(19) United States
(12) Patent Application Publication
(10) Pub. No.: US 2025/0169350 A1
(43) Pub. Date: May 22, 2025

(54) ORGANOMETALLIC COMPOUND, ORGANIC LIGHT-EMITTING DEVICE INCLUDING THE SAME AND ELECTRONIC APPARATUS INCLUDING THE ORGANIC LIGHT-EMITTING DEVICE

(71) Applicant: Samsung Electronics Co., Ltd., Suwon-si, Gyeonggi-do (KR)

(72) Inventors: Kum Hee Lee, Suwon-si (KR); Byungjoon Kang, Seoul (KR); Seungyeon Kwak, Suwon-si (KR); Sunghun Lee, Hwaseong-si (KR); Aram Jeon, Seoul (KR); Hyeonho Choi, Seoul (KR); Kyuyoung Hwang, Anyang-si (KR); Byoungki Choi, Hwaseong-si (KR); Whail Choi, Seoul (KR)

(21) Appl. No.: 18/921,536

(22) Filed: Oct. 21, 2024

Related U.S. Application Data
(63) Continuation of application No. 17/032,392, filed on Sep. 25, 2020.

(30) Foreign Application Priority Data
Sep. 26, 2019 (KR) 10-2019-0119095
Sep. 23, 2020 (KR) 10-2020-0123024

(51) Int. Cl. H10K 85/30; C07F 15/00; C09K 11/06; H10K 50/11; H10K 50/15; H10K 50/16; H10K 50/17; H10K 50/18; H10K 85/40

(52) U.S. Cl. CPC H10K 85/342; C07F 15/0033; C09K 11/06; H10K 85/361; H10K 85/40; C07B 2200/05; C09K 2211/1062; C09K 2211/185; H10K 50/11; H10K 50/15; H10K 50/16; H10K 50/17; H10K 50/171; H10K 50/18

(57) ABSTRACT

An organometallic compound represented by Formula 1:

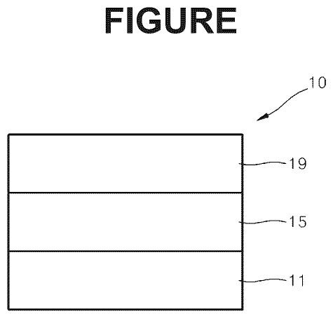

M(L₁)ₙ₁(L₂)ₙ₂ Formula 1
wherein, Formula 1, M is a transition metal, L₁ is a ligand represented by Formula 2 as provided herein, L₂ is a ligand represented by Formula 3 as provided herein, and n1 and n2 are each independently 1 or 2.

### CROSS-REFERENCE TO RELATED APPLICATION

This application is a continuation of U.S. application Ser. No. 17/032,392, filed on Sep. 25, 2020, which claims priority to and the benefit of Korean Patent Application No. 10-2019-0119095, filed on Sep. 26, 2019 in the Korean Intellectual Property Office, and Korean Patent Applications No. 10-2020-0123024, filed on Sep. 23, 2020, in the Korean Intellectual Property Office, and all the benefits accruing therefrom under 35 U.S.C. § 119, the contents of which are incorporated herein in their entireties by reference.

### BACKGROUND

### 1. Field

One or more embodiments of the present disclosure relate to an organometallic compound, an organic light-emitting device including the same and an electronic apparatus including the organic light-emitting device.

### 2. Description of Related Art

Organic light-emitting devices are self-emission devices that produce full-color images, and also have wide viewing angles, high contrast ratios, short response times, and excellent characteristics in terms of brightness, driving voltage, and response speed

An example of the organic light-emitting device may include an anode, a cathode, and an organic layer disposed between the anode and the cathode and including an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. Carriers, such as holes and electrons, recombine in the emission layer to produce excitons. These excitons transit from an excited state to a ground state, thereby generating light.

### SUMMARY

Provided are novel organometallic compounds, organic light-emitting devices using the same and an electronic apparatus including the organic light-emitting device.

Additional aspects will be set forth in part in the description which follows and, in part, will be apparent from the description, or may be learned by practice of the presented embodiments of the disclosure.

According to an aspect, an organometallic compound presented in Formula 1 is provided:

M(L₁)ₙ₁(L₂)ₙ₂ Formula 1

In Formula 1,
M may be a transition metal,
L₁ may be a ligand represented by Formula 2,
L₂ may be a ligand represented by Formula 3,
n1 and n2 may each independently be 1 or 2, when n1 is 2, two L₁ groups may be identical to or different from each other, and when n2 is 2, two L₂ groups may be identical to or different from each other.

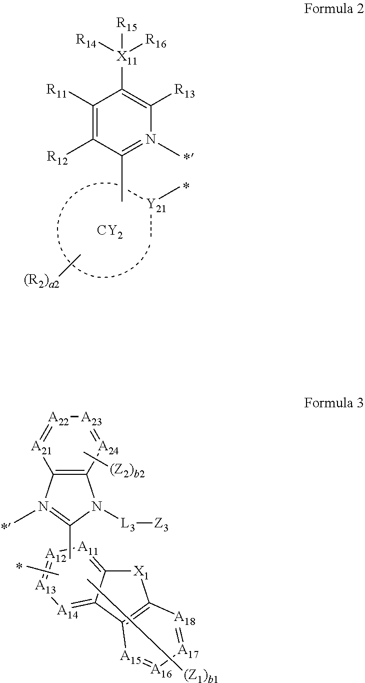

In Formulae 2 and 3,
Y₂₁ may be C or N,
ring CY₂ may be a C₅-C₃₀ carbocyclic group or C₁-C₃₀ heterocyclic group,
X₁₁ may be Si or Ge,
X₁ may be O, S, Se, N(Z₁₉), C(Z₁₉)(Z₂₀), or Si(Z₁₉)(Z₂₀),
A₁₁ to A₁₄ may each independently be C or N, wherein one of A₁₁ to A₁₄ may be C bonded to a group represented by:

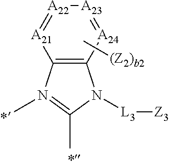

in Formula (3), and one of remaining A₁₁ to A₁₄ may be C bonded to M in Formula 1,
A₁₅ to A₁₈ and A₂₁ to A₂₄ may each independently be C or N,
at least one of A₁₁ to A₁₈ may be N,
L₃ may be a single bond, a C₅-C₃₀ carbocyclic group unsubstituted or substituted with at least one R₁₀ₐ, or a C₁-C₃₀ heterocyclic group unsubstituted or substituted with at least one R₁₀ₐ,
R₂, R₁₁ to R₁₆, Z₁ to Z₃, Z₁₉, and Z₂₀ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉) or —P(Q₈)(Q₉),
a2 is an integer from 0 to 20, and when a2 is two or more, two or more of R₂ may be identical to or different from each other,
b1 is an integer from 0 to 5, and when b1 is two or more, two or more of Z₁ may be identical to or different from each other,
b2 is an integer from 0 to 4, and when b2 is two or more, two or more of Z₂ may be identical to or different from each other,
R₁₁ and R₁₂ are optionally linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ,
two or more of a plurality of R₂ groups are optionally linked to each other to form a C₅-C₃₀ carbocyclic group that is unsubstituted or substituted with at least one R₁₀ₐ, or two or more of the plurality of R₂ groups are optionally linked to each other to form a C₁-C₃₀ heterocyclic group that is unsubstituted or substituted with at least one R₁₀ₐ,
two or more of a plurality of Z₁ groups are optionally linked to each other to form a C₅-C₃₀ carbocyclic group that is unsubstituted or substituted with at least one R₁₀ₐ, or two or more of the plurality of Z₁ groups are optionally linked to each other to form a C₁-C₃₀ heterocyclic group that is unsubstituted or substituted with at least one R₁₀ₐ,
two or more of a plurality of Z₂ groups are optionally linked to each other to form a C₅-C₃₀ carbocyclic group that is unsubstituted or substituted with at least one R₁₀ₐ, or two or more of a plurality of Z₂ groups are optionally linked to each other to form a C₁-C₃₀ heterocyclic group that is unsubstituted or substituted with at least one R₁₀ₐ,
R₁₀ₐ is deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
*, *′, and *″ each indicate a binding site to M in Formula 1,
wherein a substituent of the substituted C₁-C₆₀ alkyl group, the substituted C₂-C₆₀ alkenyl group, the substituted C₂-C₆₀ alkynyl group, the substituted C₁-C₆₀ alkoxy group, substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₇-C₆₀ arylalkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted C₂-C₆₀ alkylheteroaryl group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, carboxylic acid group or a salt thereof, sulfonic acid group or a salt thereof, phosphoric acid group or a salt thereof, a C₁-C₆₀ alkyl group, a C₂-C₆₀ alkenyl group, a C₂-C₆₀ alkynyl group, C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, carboxylic acid group or a salt thereof, sulfonic acid group or a salt thereof, phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a C₂-C₆₀ alkylheteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, carboxylic acid group or a salt thereof, sulfonic acid group or a salt thereof, phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof, and
wherein Q₁ to Q₉, Q₁₁ to Q₁₉, Q₂₁ to Q₂₉, and Q₃₁ to Q₃₉ may each independently be: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, —F, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, —F, a C₁-C₆₀ alkyl group, a C₆-C₆₀ aryl group, or a combination thereof; a C₆-C₆₀ aryloxy group; a C₆-C₆₀ arylthio group; a C₇-C₆₀ arylalkyl group; a C₁-C₆₀ heteroaryl group; a C₁-C₆₀ heteroaryloxy group; a C₁-C₆₀ heteroarylthio group; a C₂-C₆₀ heteroarylalkyl group; a C₂-C₆₀ alkylheteroaryl group; a monovalent non-aromatic condensed polycyclic group; or a monovalent non-aromatic condensed heteropolycyclic group.

Another aspect provides an organic light-emitting device including a first electrode; a second electrode; and an organic layer including an emission layer disposed between the first electrode and the second electrode, wherein the organic layer includes at least one organometallic compound described above.

The organometallic compound may be included in the emission layer, and the organometallic compound included in the emission layer may serve as a dopant.

Another aspect provides an electronic apparatus including the organic light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which FIGURE is a schematic view of a structure of an organic light-emitting device according to an embodiment.

FIGURE shows a schematic cross-sectional view of an organic light-emitting device according to an embodiment.

### DETAILED DESCRIPTION

Reference will now be made in detail to exemplary embodiments, examples of which are illustrated in the accompanying drawing, wherein like reference numerals refer to like elements throughout. In this regard, the present exemplary embodiments may have different forms and should not be construed as being limited to the descriptions set forth herein. Accordingly, the exemplary embodiments are merely described below, by referring to the FIGURES, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to a cross section illustration that is a schematic illustration of one or more idealized embodiments. As such, variations from the shapes of the illustration as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the FIGURE are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

An aspect of the present disclosure provides an organometallic compound represented by Formula 1 below:

M(L₁)ₙ₁(L₂)ₙ₂ Formula 1

In Formula 1, M may be a transition metal.

For example, M may be a first-row transition metal, a second-row transition metal, or a third-row transition metal of the Periodic Table of Elements.

In one or more embodiments, M may be iridium (Ir), platinum (Pt), osmium (Os), titanium (Ti), zirconium (Zr), hafnium (Hf), europium (Eu), terbium (Tb), thulium (Tm), or rhodium (Rh).

In one or more embodiments, M may be Ir, Pt, Os, or Rh.

In Formula 1, L₁ may be a ligand represented by Formula 2 below, and L₂ may be a ligand represented by Formula 3 below:

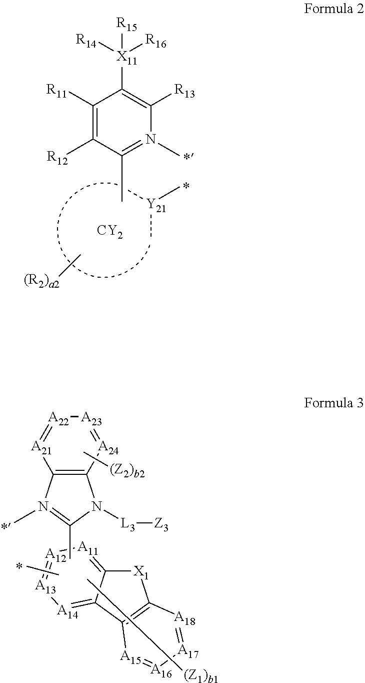

Formulae 2 and 3 may each be understood by referring to the corresponding descriptions thereof provided herein.

In Formula 1, L₁ and L₂ may be different from each other.

In Formula 1, n1 and n2 indicate the number of L₁ groups and the number of L₂ groups, respectively, and may each independently be 1 or 2. When n1 is 2, the two L₁ groups may be identical to or different from each other, and when n2 is 2, the two L₂ groups may be identical to or different from each other.

For example, in Formula 1, i) n1 may be 2, and n2 may be 1; or ii) n1 may be 1, and n2 may be 2, but embodiments of the present disclosure are not limited thereto.

In one or more embodiments, in Formula 1, i) M may be Ir or Os, and the sum of n1+n2 may be 3 or 4; or ii) M may be Pt, and the sum of n1+n2 may be 2.

In Formula 2, Y₂₁ may be C or N.

For example, Y₂₁ may be C.

In Formula 2, ring CY₂ may be a C₅-C₃₀ carbocyclic group or a C₁-C₃₀ heterocyclic group.

For example, ring CY₂ may be i) a first ring, ii) a second ring, iii) a condensed ring in which two or more first rings are condensed with each other, iv) a condensed ring in which two or more second rings are condensed with each other, or v) a condensed ring in which one or more first rings and one or more second rings are condensed with each other.

The first ring may be a cyclopentane group, a cyclopentadiene group, a furan group, a thiophene group, a pyrrole group, a silole group, a germole group, a borole group, a selenophene group, a phosphole group, an oxazole group, an oxadiazole group, an oxatriazole group, a thiazole group, a thiadiazole group, a thiatriazole group, a pyrazole group, an imidazole group, a triazole group, a tetrazole group, an azasilole group, an azagermole group, an azaborole group, an azaselenophene group, or an azaphosphole group.

The second ring may be an adamantane group, a norbornane group (a bicyclo[2.2.1]heptane group), a norbornene group, a bicyclo[1.1.1]pentane group, a bicyclo[2.1.1]hexane group, a bicyclo[2.2.2]octane group, a cyclohexane group, a cyclohexene group, a benzene group, a pyridine group, a pyrimidine group, a pyrazine group, a pyridazine group, or a triazine group.

In one or more embodiments, ring CY₂ may be a cyclopentene group, a cyclohexane group, a cyclohexene group, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, an adamantane group, a norbornane group, or a norbornene group.

In one or more embodiments, ring CY₂ may be a benzene group, a naphthalene group, an anthracene group, a phenanthrene group, a 1,2,3,4-tetrahydronaphthalene group, an indole group, a carbazole group, a fluorene group, a dibenzosilole group, a dibenzothiophene group, a dibenzofuran group, an azabenzosilole group, a pyridine group, a benzimidazole group, a benzoxazole group, or a benzothiazole group.

In one or more embodiments, ring CY₂ may be a benzene group, a naphthalene group, an anthracene group, a phenanthrene group, a 1,2,3,4-tetrahydronaphthalene group, a carbazole group, a fluorene group, a dibenzosilole group, a dibenzothiophene group, or a dibenzofuran group.

In Formula 2, X₁₁ may be Si or Ge.

In Formula 3, X₁ may be O, S, Se, N(Z₁₉), C(Z₁₉)(Z₂₀), or Si(Z₁₉)(Z₂₀). Z₁₉ and Z₂₀ may each be understood by referring to the corresponding descriptions thereof provided herein.

For example, X₁ may be O, S, or N(Z₁₉).

In Formula 3, A₁₁ to A₁₄ may each independently be C or N, wherein one of A₁₁ to A₁₄ may be C bonded to a group represented by

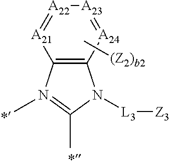

in Formula 3, and one of remaining A₁₁ to A₁₄ may be C bonded to M in Formula 1.

In Formula 3, A₁₅ to A₁₈ and A₂₁ to A₂₄ may each independently be C or N.

In Formula 3, at least one of A₁₁ to A₁₈ may be N.

For example, one or two of A₁₁ to A₁₈ in Formula 3 may be N.

In one or more embodiments, in Formula 3, one or two of A₁₃ to A₁₈ may be N.

In one or more embodiments, in Formula 3, one or two of A₁₅ to A₁₈ may be N.

In one or more embodiments, in Formula 3, A₁₈ may be N.

In one or more embodiments, A₂₁ to A₂₄ in Formula 3 may each be C.

In one or more embodiments, at least one of A₂₁ to A₂₄ (for example, one or two of A₂₁ to A₂₄) in Formula 3 may be N.

In Formula 3, L₃ may be a single bond, a C₅-C₃₀ carbocyclic group unsubstituted or substituted with at least one R₁₀ₐ, or a C₁-C₃₀ heterocyclic group unsubstituted or substituted with at least one R₁₀ₐ.

For example, L₃ may be:
a single bond; or
a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group, each unsubstituted or substituted with at least one R₁₀ₐ. It is to be understood that the foregoing are divalent groups in the case of L₃.

In one or more embodiments, L₃ in Formula 3 may be:
a single bond; or
a benzene group unsubstituted or substituted with at least one R₁₀ₐ.

In one or more embodiments, L₃ in Formula 3 may be:
a single bond; or
a benzene group, a naphthalene group, a dibenzofuran group, or a dibenzothiophene group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof.

In Formulae 2 and 3, R₂, R₁₁ to R₁₆, Z₁ to Z₃, Z₁₉, and Z₂₀ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉).

Q₁ to Q₉ may each independently be: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, —F, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, —F, a C₁-C₆₀ alkyl group, a C₆-C₆₀ aryl group, or a combination thereof; a C₆-C₆₀ aryloxy group; a C₆-C₆₀ arylthio group; a C₇-C₆₀ arylalkyl group; a C₁-C₆₀ heteroaryl group; a C₁-C₆₀ heteroaryloxy group; a C₁-C₆₀ heteroarylthio group; a C₂-C₆₀ heteroarylalkyl group; a C₂-C₆₀ alkylheteroaryl group; a monovalent non-aromatic condensed polycyclic group; or a monovalent non-aromatic condensed heteropolycyclic group.

For example, R₂, R₁₁ to R₁₆, Z₁ to Z₃, Z₁₉, and Z₂₀ in Formulae 2 and 3 may each independently be:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterated C₁-C₂₀ alkyl group, a cyclopentyl group, a cyclohexyl group, a cycloheptyl group, a cyclooctyl group, an adamantanyl group, a norbornanyl group (a bicyclo[2.2.1]heptyl group), a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl) cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or a combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterated C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, —Si(Q₃₃)(Q₃₄)(Q₃₅), —Ge(Q₃₃)(Q₃₄)(Q₃₅), or a combination thereof; or
—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉), and
Q₁ to Q₉ and Q₃₃ to Q₃₅ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, an neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₂₀ alkyl group, a phenyl group, or a combination thereof.

For example, in one or more embodiments each of R₂, Z₁ and Z₂ may not be hydrogen.

In one or more embodiments, R₂, R₁₁ to R₁₃, Z₁ to Z₃, Z₁₉ and Z₂₀ in Formulae 2 and 3 may each independently be:
hydrogen, deuterium, —F, or a cyano group; or
a C₁-C₂₀ alkyl group, a C₃-C₁₀ cycloalkyl group, a phenyl group, a naphthyl group, a pyridinyl group, a furanyl group, a thiophenyl group, a benzofuranyl group, a benzothiophenyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, —Si(Q₃₃)(Q₃₄)(Q₃₅), —Ge(Q₃₃)(Q₃₄)(Q₃₅), or a combination thereof.

In one or more embodiments, R₁₄ to R₁₆ in Formula 2 may each independently be a C₁-C₂₀ alkyl group, a C₃-C₁₀ cycloalkyl group, a phenyl group, a naphthyl group, a pyridinyl group, a furanyl group, a thiophenyl group, a benzofuranyl group, a benzothiophenyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof.

In one or more embodiments, R₁₄ to R₁₆ in Formula 2 may each independently be —CH₃, —CH₂CH₃, —CD₃, —CD₂H, —CDH₂, —CH₂CD₃, or —CD₂CH₃.

In one or more embodiments, R₁₄ to R₁₆ in Formula 2 may be the same as each other or different from each other.

In one or more embodiments, R₁₁ in Formula 2 is not hydrogen.

In one or more embodiments, R₁₁ in Formula 2 is not hydrogen or a methyl group.

In one or more embodiments, R₁₁ in Formula 2 is not hydrogen, a methyl group, or a cyano group.

In one or more embodiments, in Formula 2, R₁₁ is not hydrogen, and R₁₂ and R₁₃ are hydrogen.

In one or more embodiments, R₁₁ in Formula 2 may be a group including at least two carbons, at least three carbons or at least four carbons.

In one or more embodiments, R₁₁ in Formula 2 may be:
a methyl group, substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof; or
a C₂-C₂₀ alkyl group, a C₃-C₁₀ cycloalkyl group, a phenyl group, a naphthyl group, a pyridinyl group, a furanyl group, a thiophenyl group, a benzofuranyl group, a benzothiophenyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof.

In one or more embodiments, Z₃ may in Formula 3 be a C₆-C₂₀ aryl group substituted with at least one C₁-C₂₀ alkyl group and at least one C₆-C₂₀ aryl group at the same time.

In one or more embodiments, Formula 3 may satisfy at least one of Condition A and Condition B as follows:

### Condition A:

L₃ is a C₅-C₃₀ carbocyclic group unsubstituted or substituted with at least one R₁₀ₐ, or a C₁-C₃₀ heterocyclic group unsubstituted or substituted with at least one R₁₀ₐ; and

### Condition B:

Z₃ is a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

In some embodiments, R₂, R₁₁ to R₁₆, Z₁ to Z₃, Z₁₉ and Z₂₀ in Formulae 2 and 3 may each independently be hydrogen, deuterium, —F, a cyano group, a nitro group, —SF₅, —CH₃, —CD₃, —CD₂H, —CDH₂, —CF₃, —CF₂H, —CFH₂, —OCH₃, —OCDH₂, —OCD₂H, —OCD₃, —SCH₃, —SCDH₂, —SCD₂H, —SCD₃, a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-230, a group represented by one of Formulae 9-201 to 9-230 in which at least one hydrogen is substituted with deuterium, a group represented by one of Formulae 9-201 to 9-230 in which at least one hydrogen is substituted with —F, a group represented by one of Formulae 10-1 to 10-145, a group represented by one of Formulae 10-1 to 10-145 in which at least one hydrogen is substituted with deuterium, a group represented by one of Formulae 10-1 to 10-145 in which at least one hydrogen is substituted with —F, a group represented by one of Formulae 10-201 to 10-354, a group represented by one of Formulae 10-201 to 10-354 in which at least one hydrogen is substituted with deuterium, a group represented by one of Formulae 10-201 to 10-354 in which at least one hydrogen is substituted with —F, —Si(Q₃)(Q₄)(Q₅), or —Ge(Q₃)(Q₄)(Q₅), wherein Q₃ to Q₅ may respectively be understood by referring to the descriptions of Q₃ to Q₅ provided herein.

In some embodiments, R₁₁ in Formula 2 may be a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-230, a group represented by one of Formulae 9-201 to 9-230 in which at least one hydrogen is substituted with deuterium, a group represented by one of Formulae 9-201 to 9-230 in which at least one hydrogen is substituted with —F, a group represented by one of Formulae 10-1 to 10-145, a group represented by one of Formulae 10-1 to 10-145 in which at least one hydrogen is substituted with deuterium, a group represented by one of Formulae 10-1 to 10-145 in which at least one hydrogen is substituted with —F, a group represented by one of Formulae 10-201 to 10-354, a group represented by one of Formulae 10-201 to 10-354 in which at least one hydrogen is substituted with deuterium, or a group represented by one of Formulae 10-201 to 10-354 in which at least one hydrogen is substituted with —F.

In some embodiments, Z₃ in Formula 3 may be a group represented by one of Formulae 10-12 to 10-145, a group represented by one of Formulae 10-12 to 10-145 in which at least one hydrogen is substituted with deuterium, a group represented by one of Formulae 10-12 to 10-145 in which at least one hydrogen is substituted with —F, a group represented by one of Formulae 10-201 to 10-354, a group represented by one of Formulae 10-201 to 10-354 in which at least one hydrogen is substituted with deuterium, or a group represented by one of Formulae 10-201 to 10-354 in which at least one hydrogen is substituted with —F:

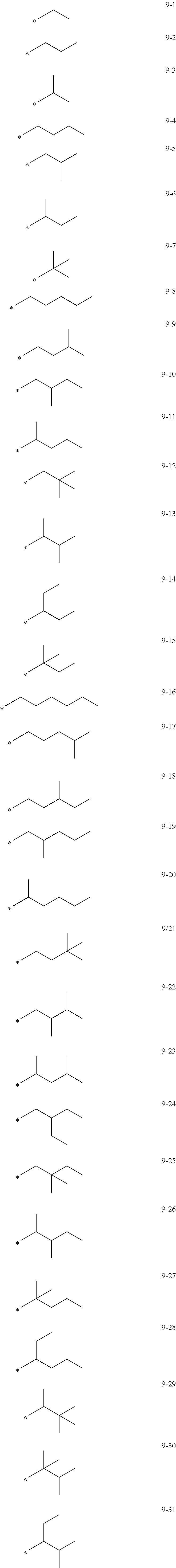

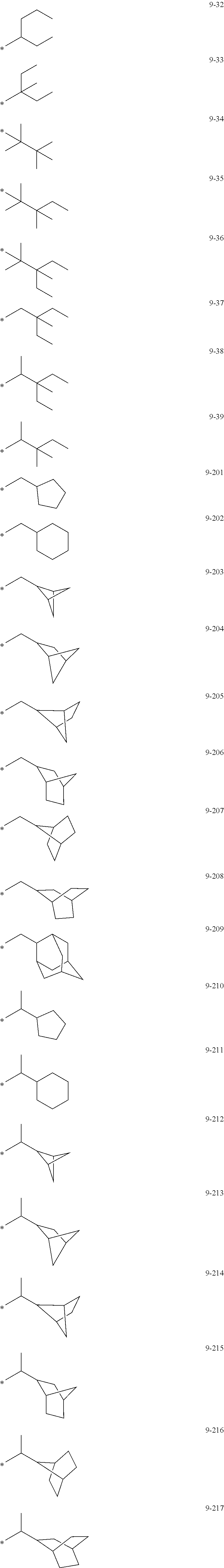

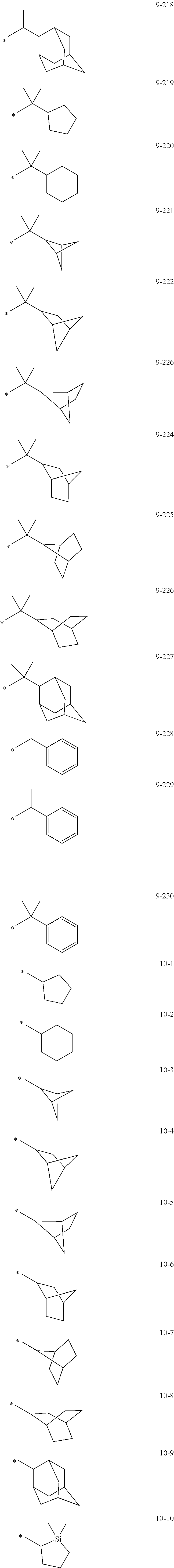

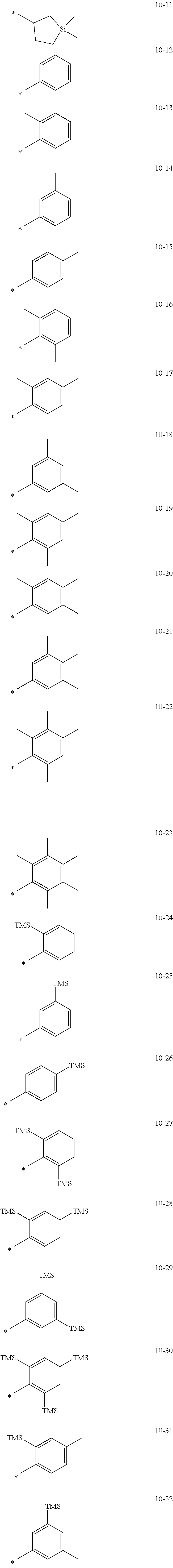

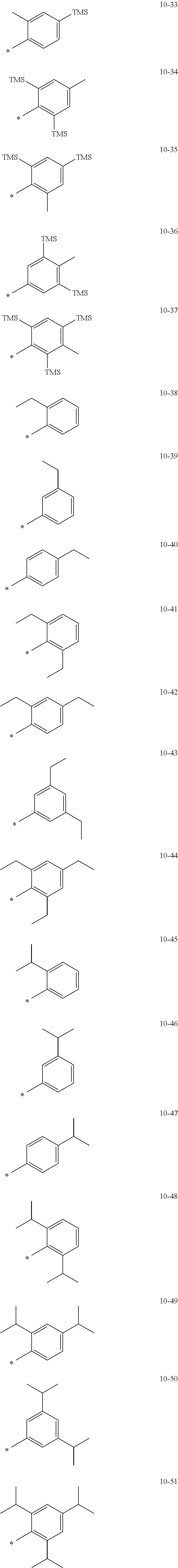

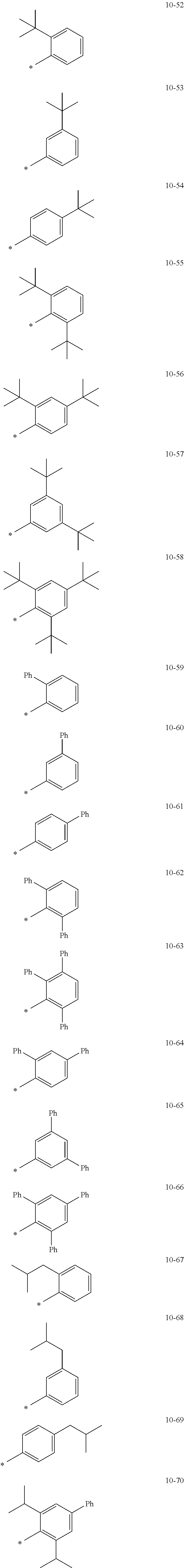

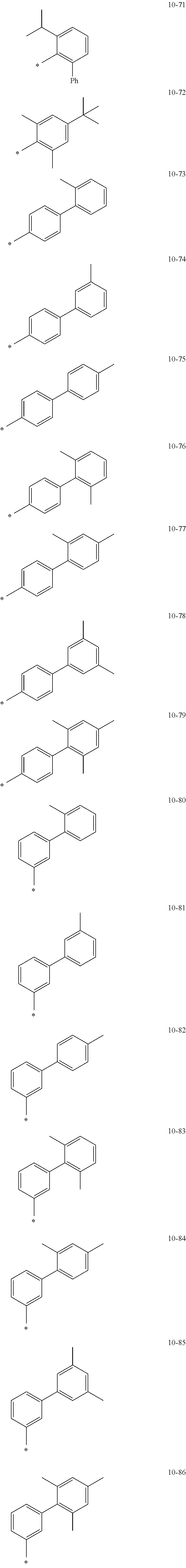

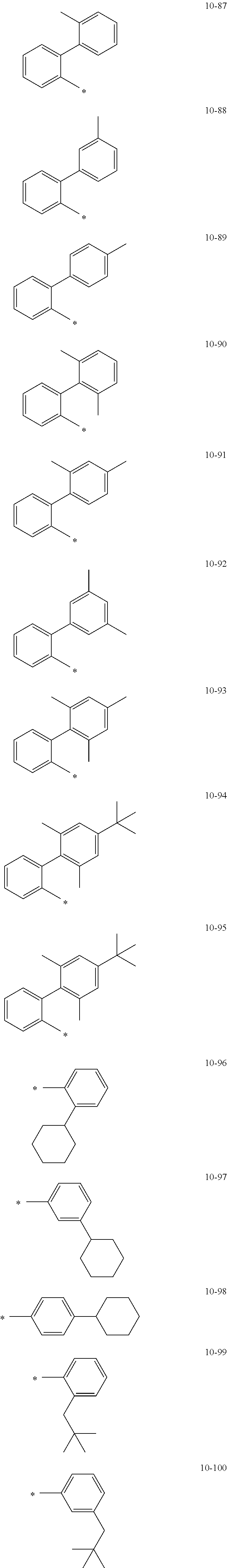

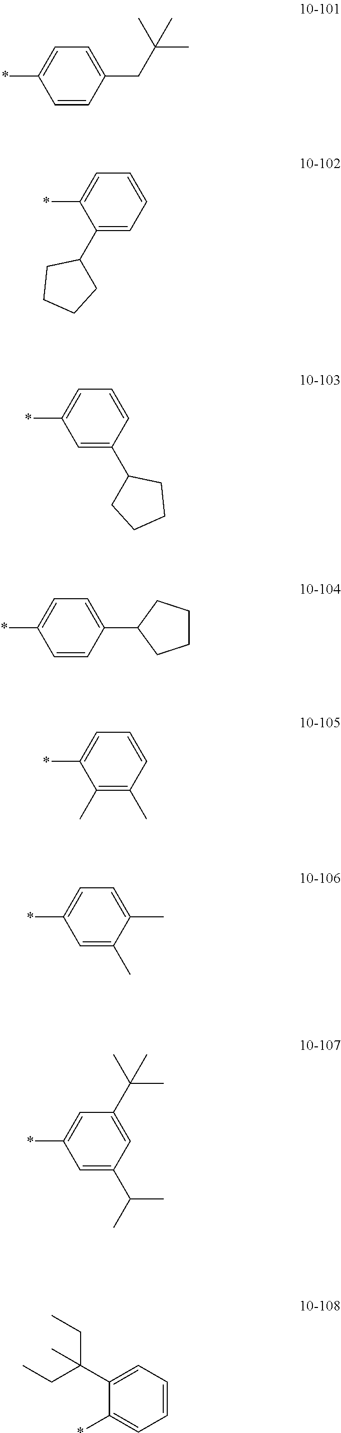

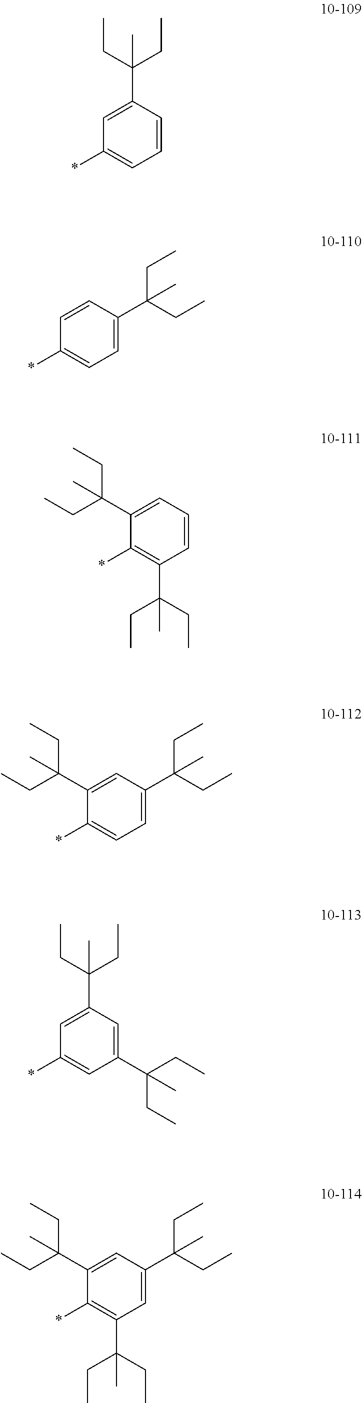

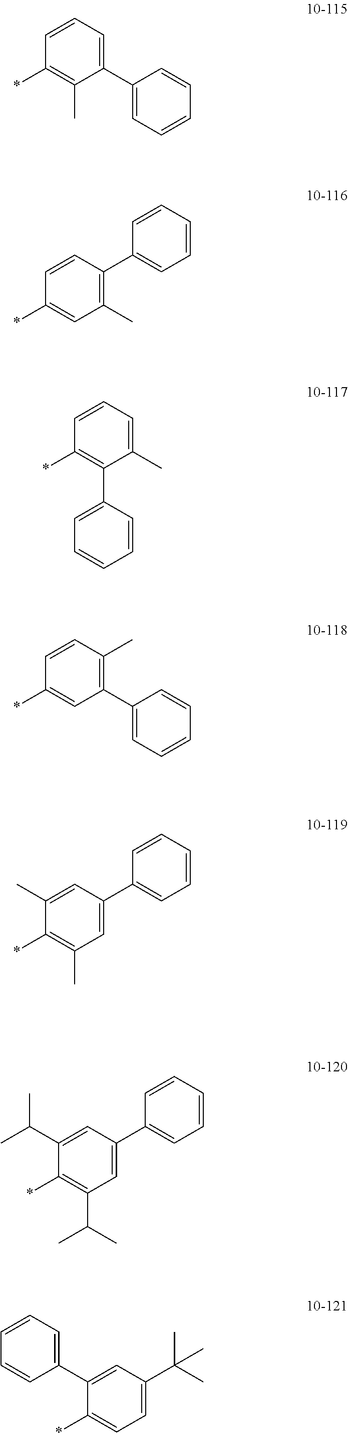

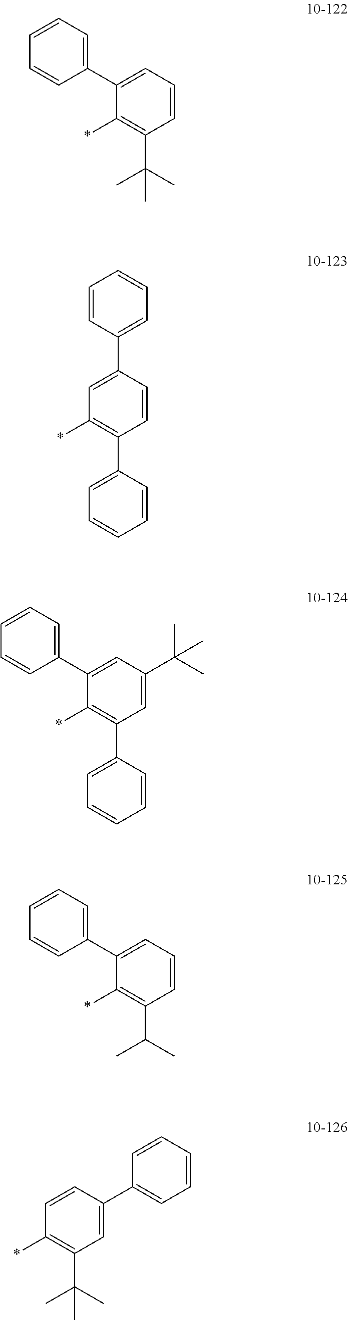 [SMILES: *c1c(-c2ccccc2)cccc1C(C)(C)C ; *c1cc(-c2ccccc2)ccc1-c1ccccc1 ; *c1c(-c2ccccc2)cc(C(C)(C)C)cc1-c1ccccc1 ; *c1c(-c2ccccc2)cccc1C(C)C ; *c1ccc(-c2ccccc2)cc1C(C)(C)C]

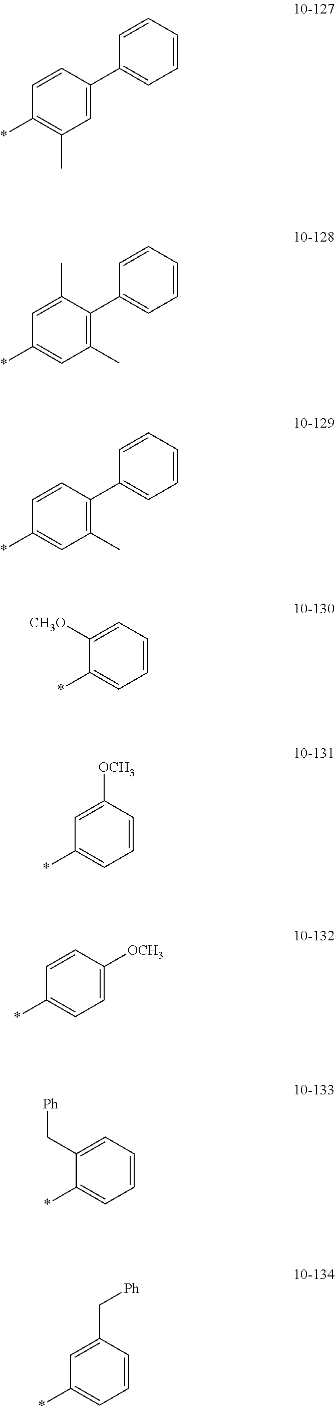

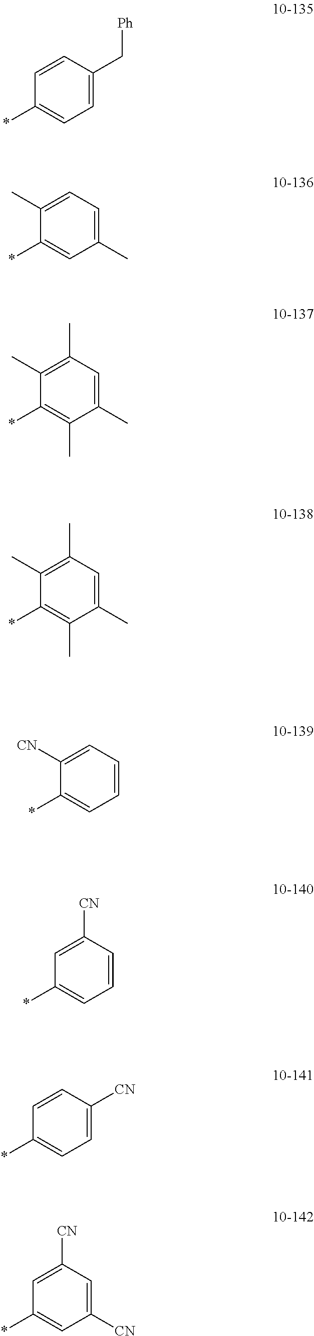

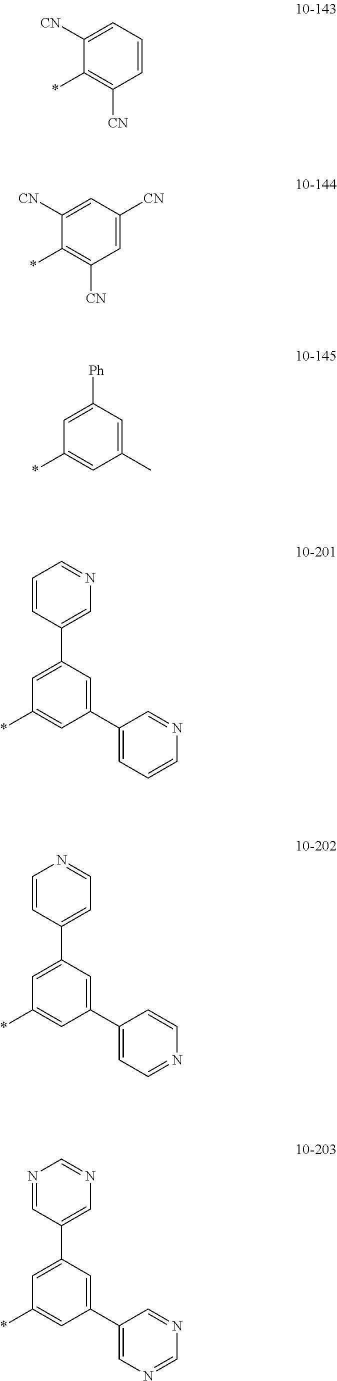

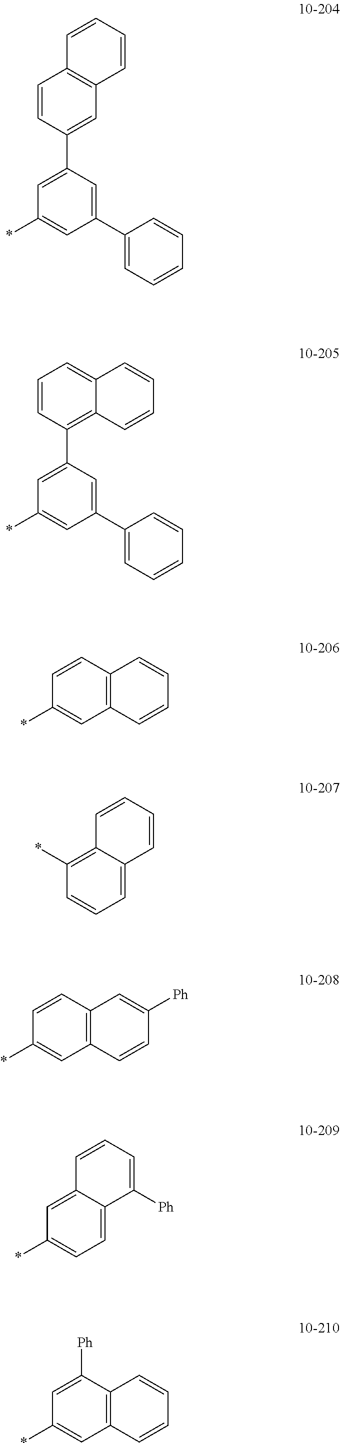

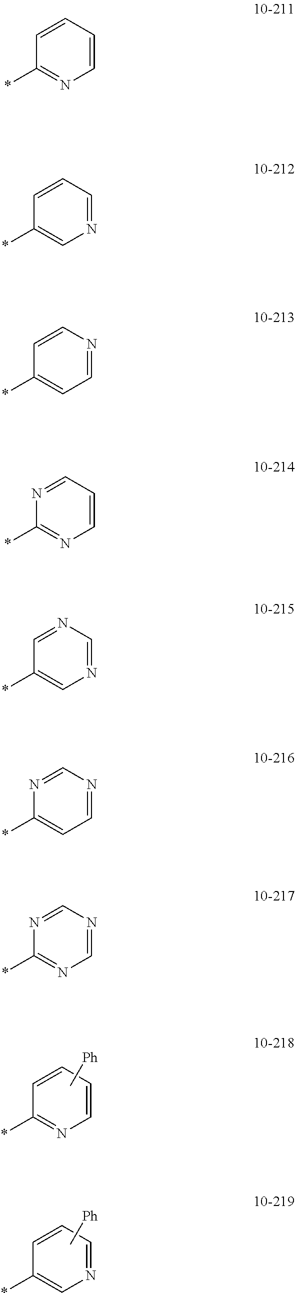

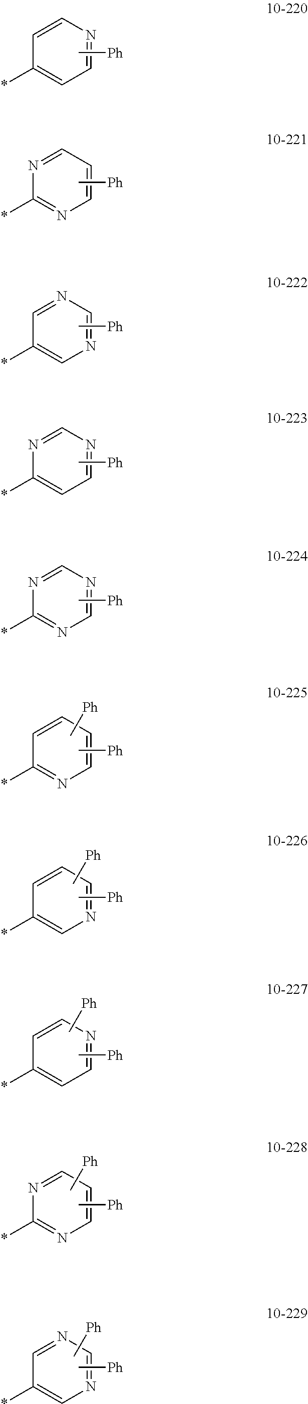

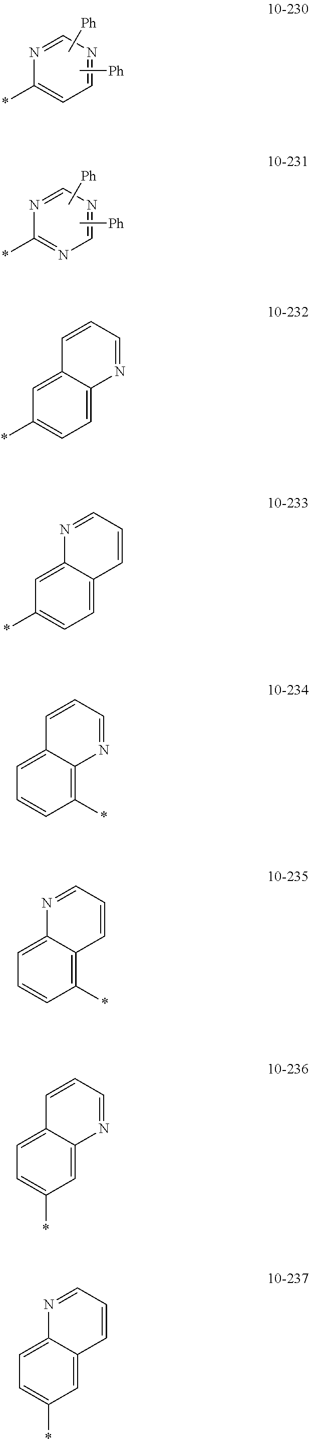

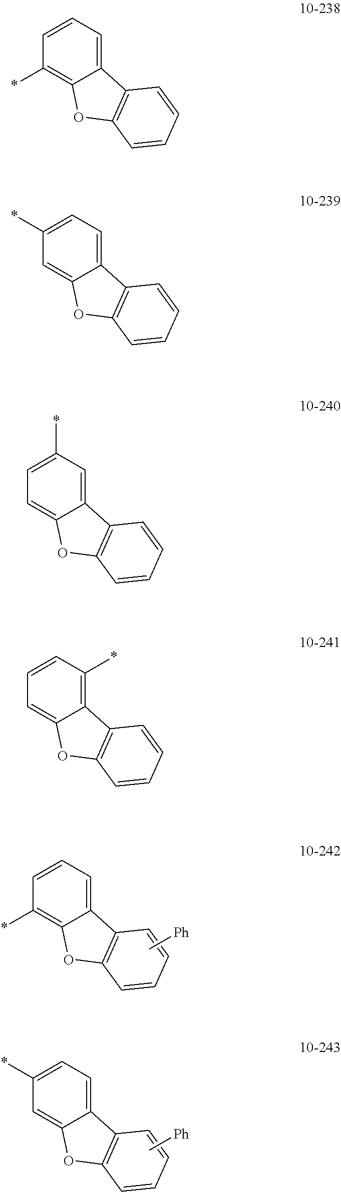

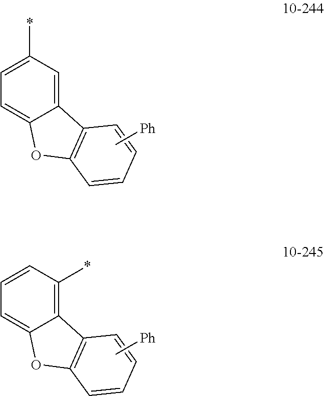

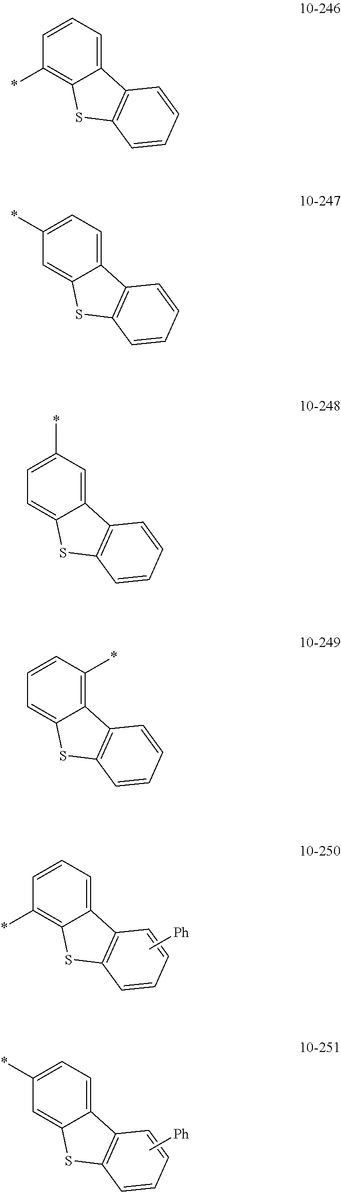

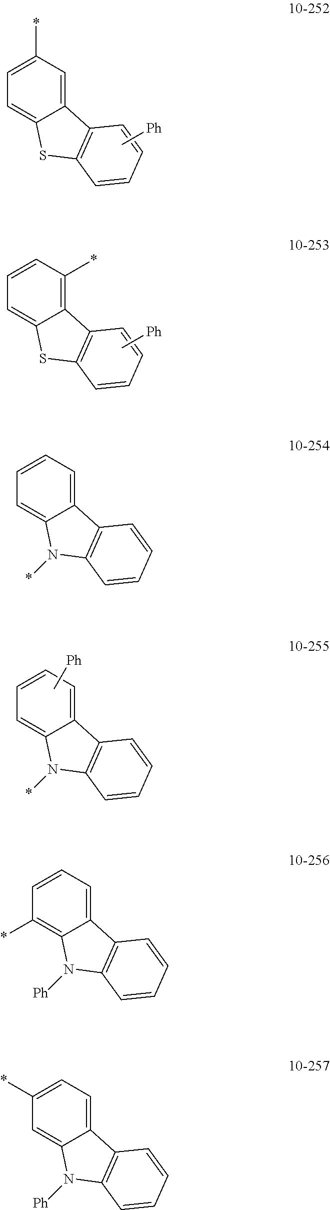

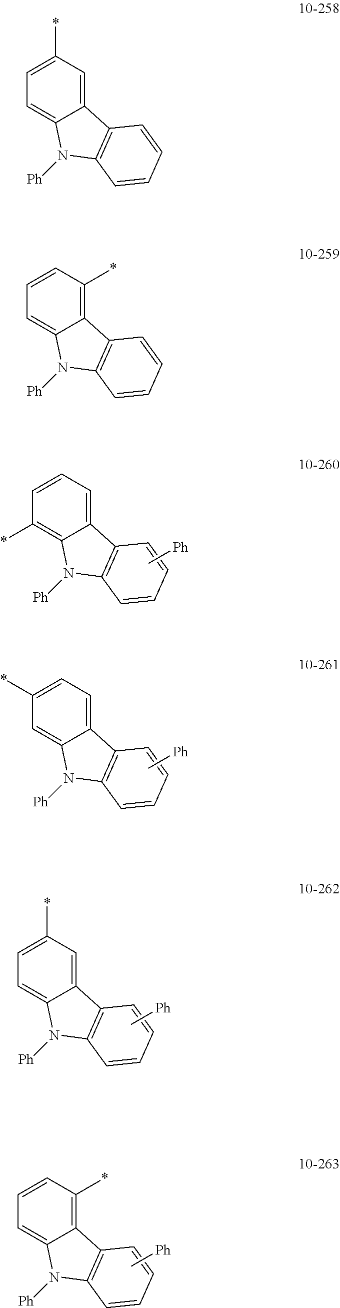

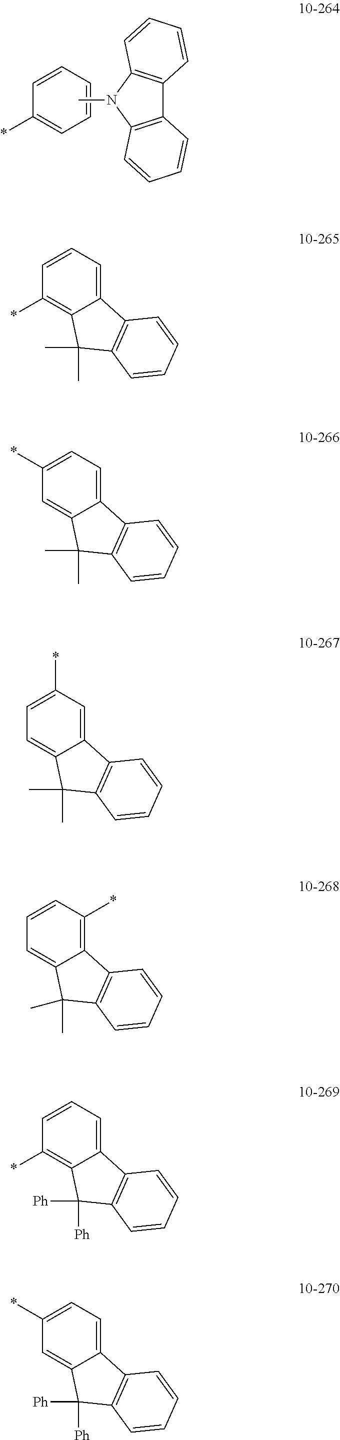

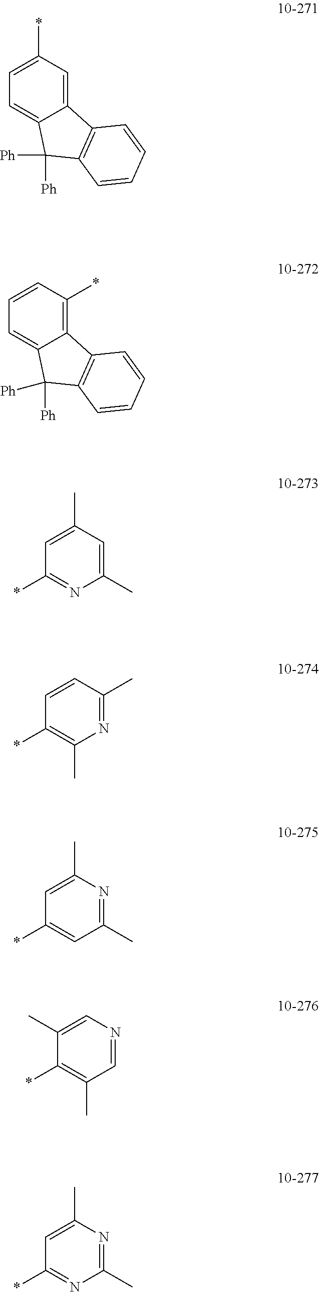

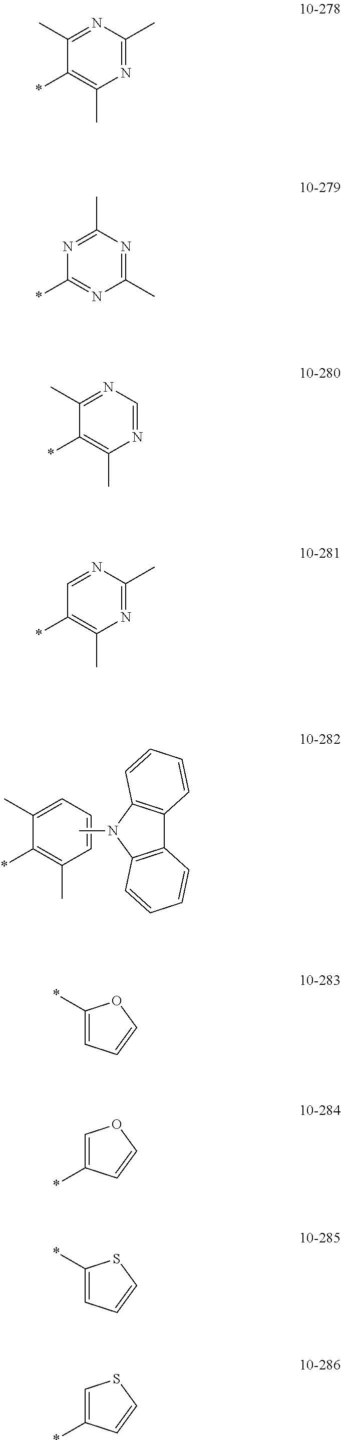

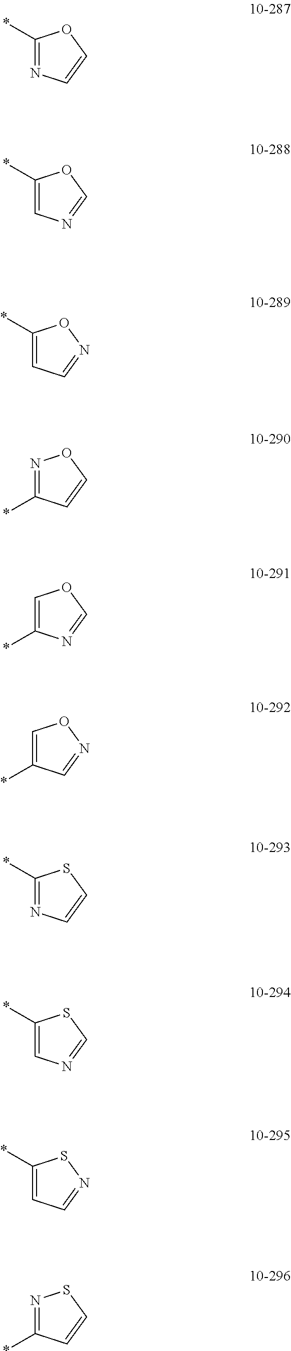

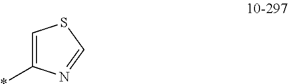 [SMILES: *c1cscn1]

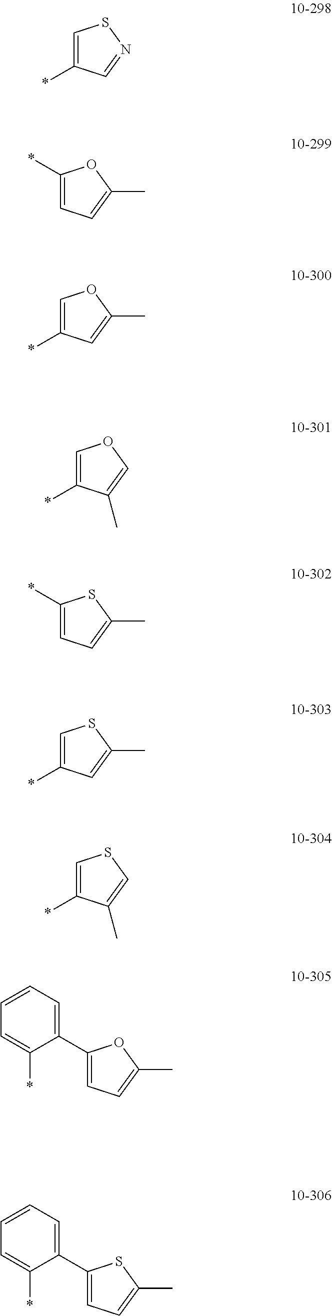

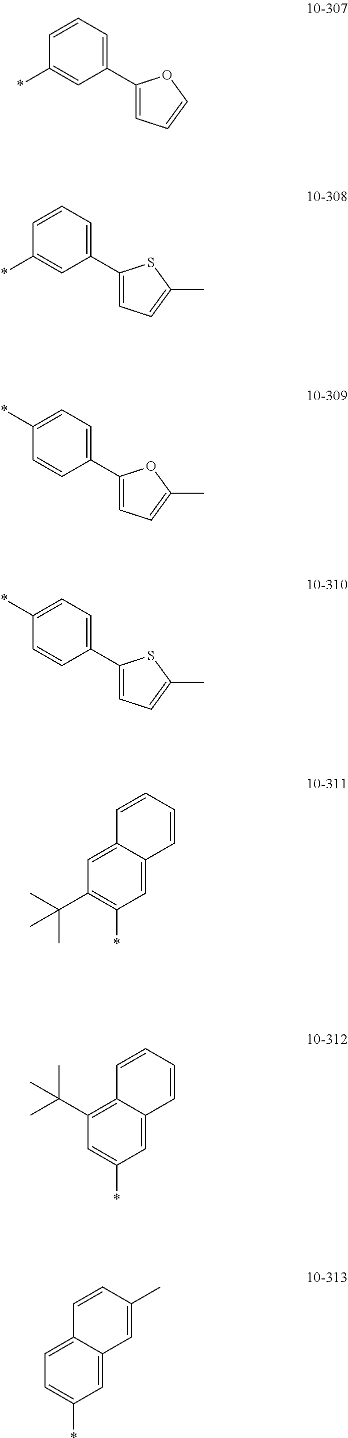

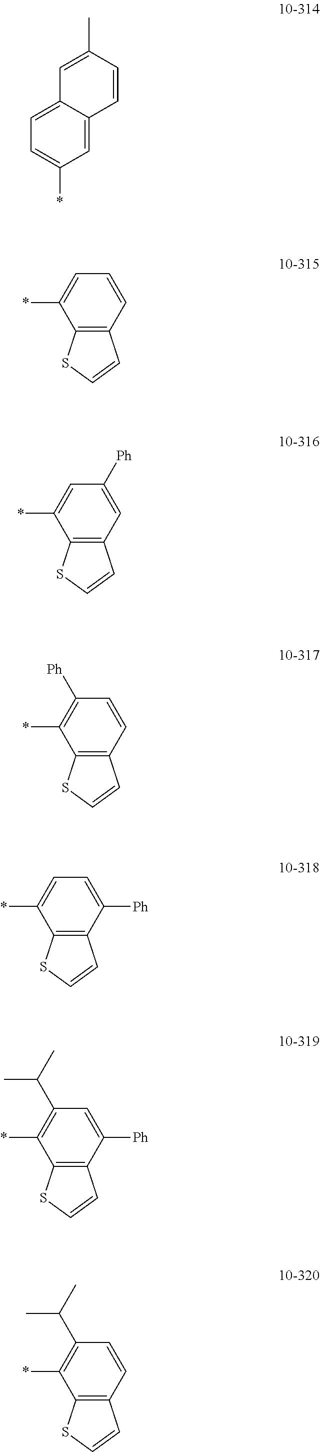

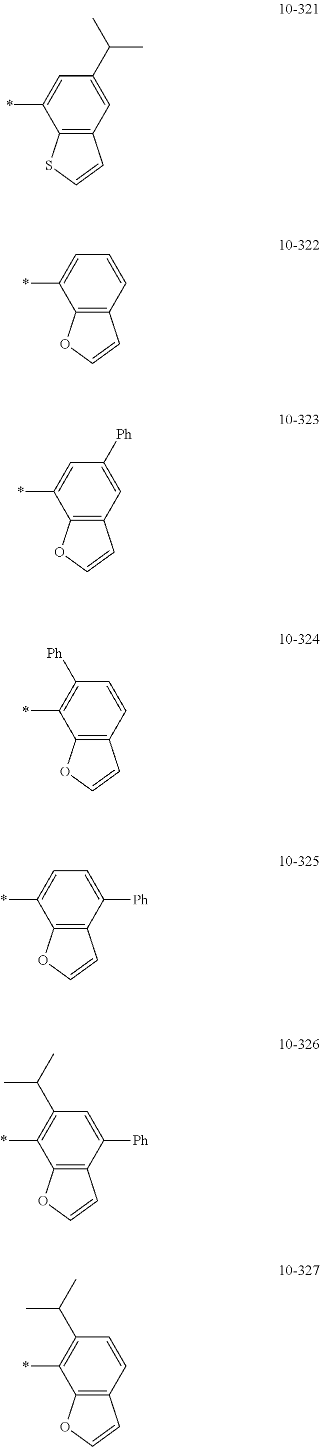

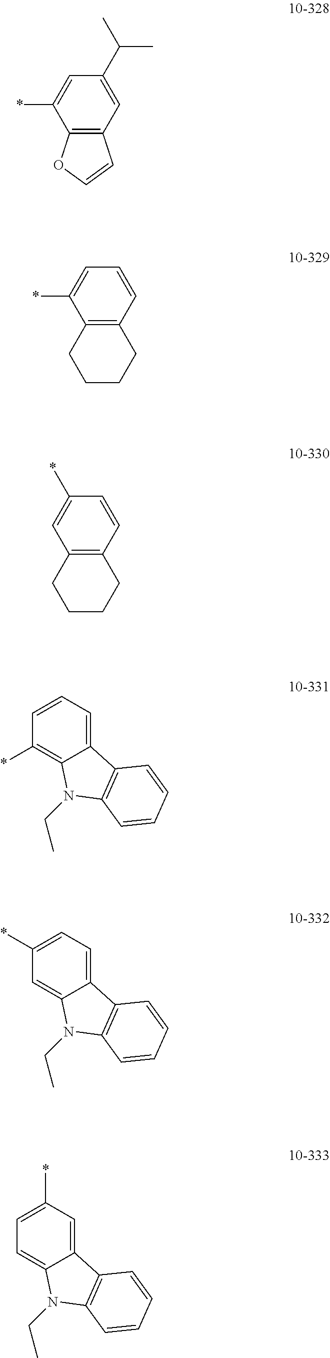 [SMILES: *c1cc(C(C)C)cc2ccoc12 ; *c1cccc2c1CCCC2 ; *c1ccc2c(c1)CCCC2 ; *c1cccc2c3ccccc3n(CC)c12 ; *c1ccc2c3ccccc3n(CC)c2c1 ; *c1ccc2c(c1)c1ccccc1n2CC]

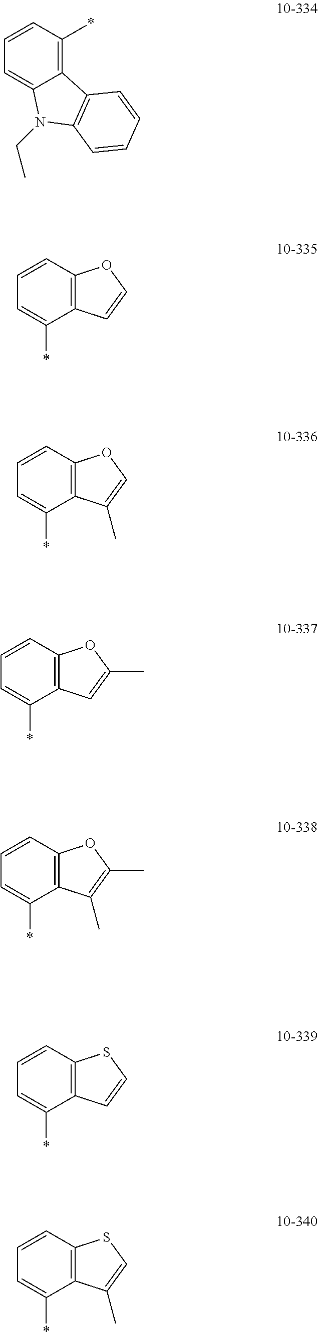

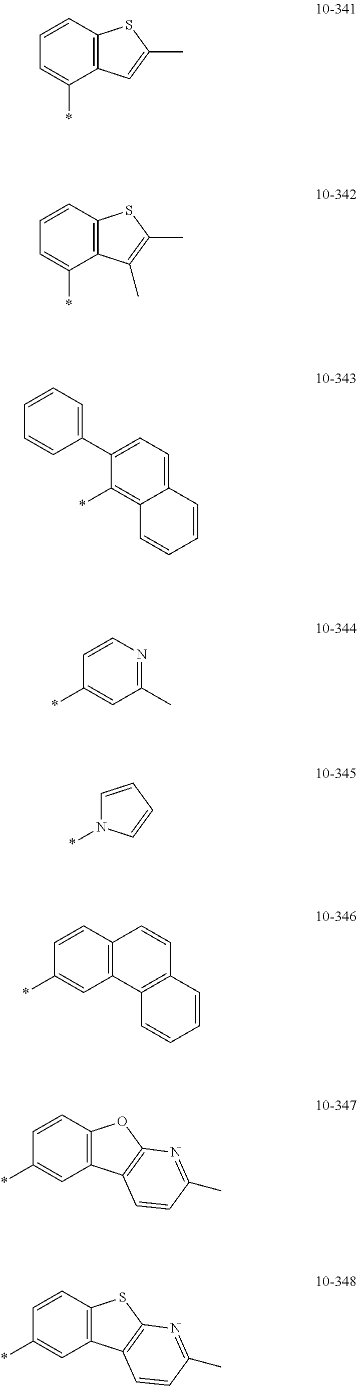

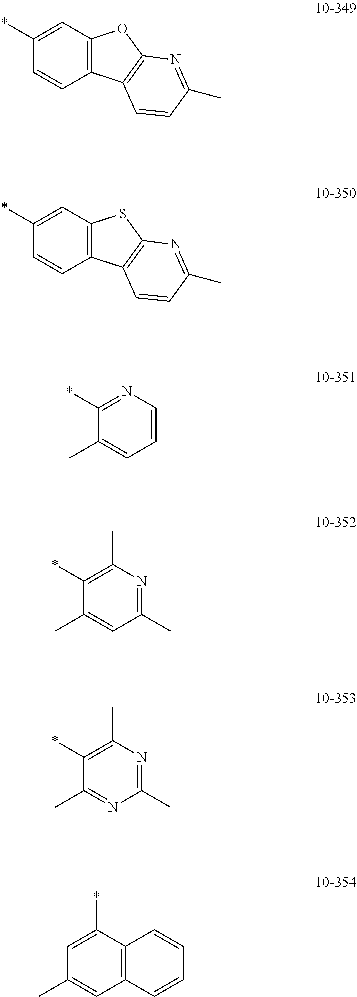

In Formulae 9-1 to 9-39, 9-201 to 9-230, 10-1 to 10-145, and 10-201 to 10-354, * indicates a binding site to an adjacent atom, “Ph” represents a phenyl group, “TMS” represents a trimethylsilyl group, “TMG” represents a trimethylgermyl group and “OMe” represents a methoxy group.

The “group represented by one of Formulae 9-1 to 9-39 in which at least one hydrogen is substituted with deuterium” and the “group represented by one of Formulae 9-201 to 9-230 in which at least one hydrogen is substituted with deuterium” may each be, for example, a group represented by one of Formulae 9-501 to 9-514 and 9-601 to 9-637:

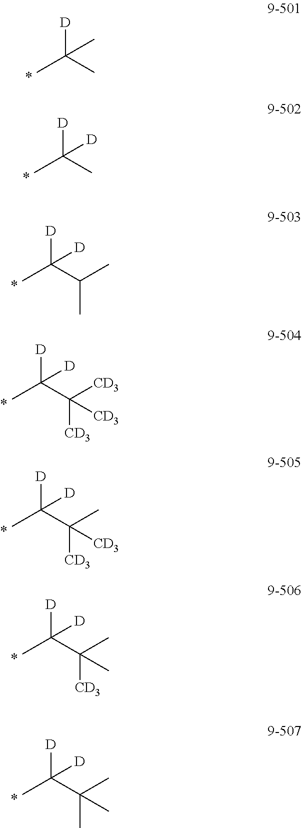

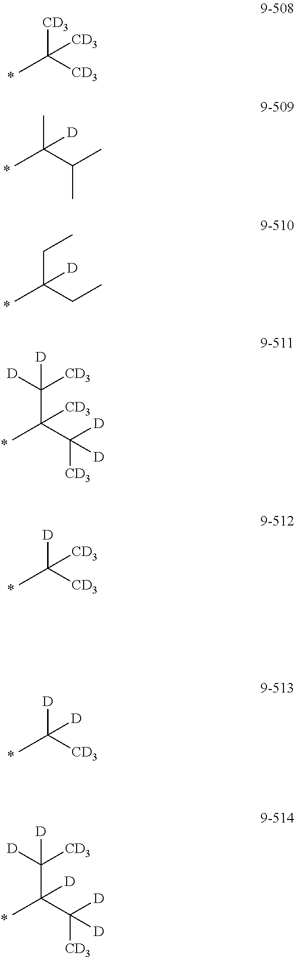

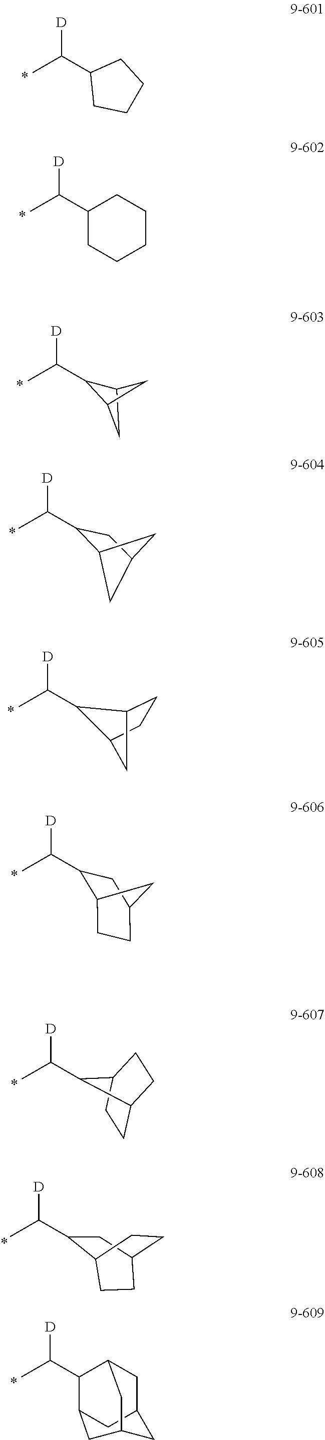

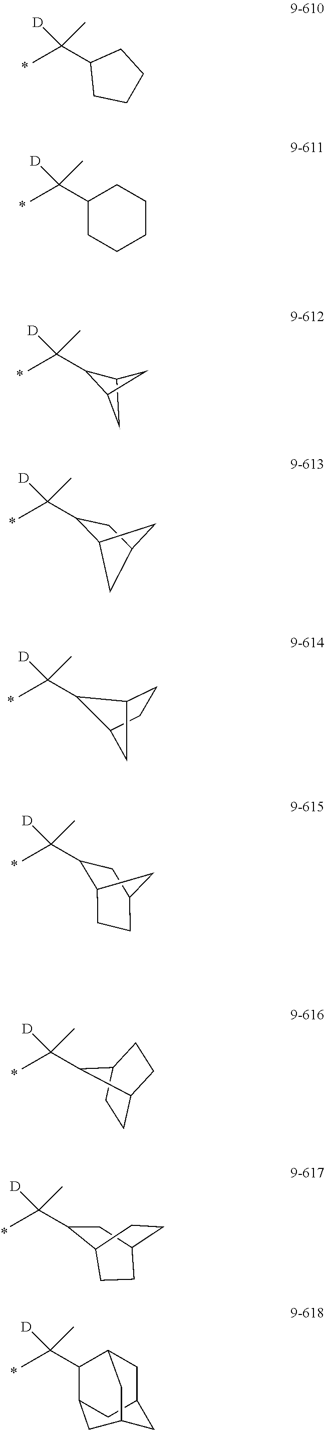

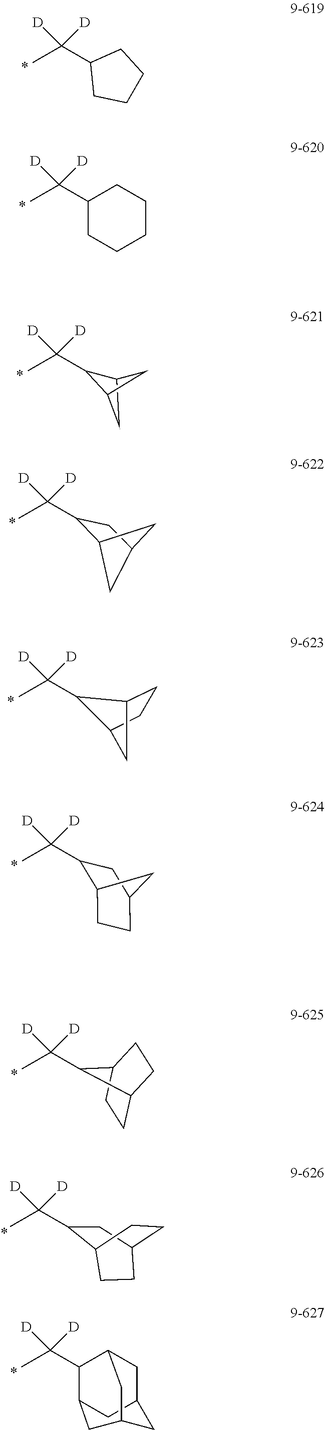

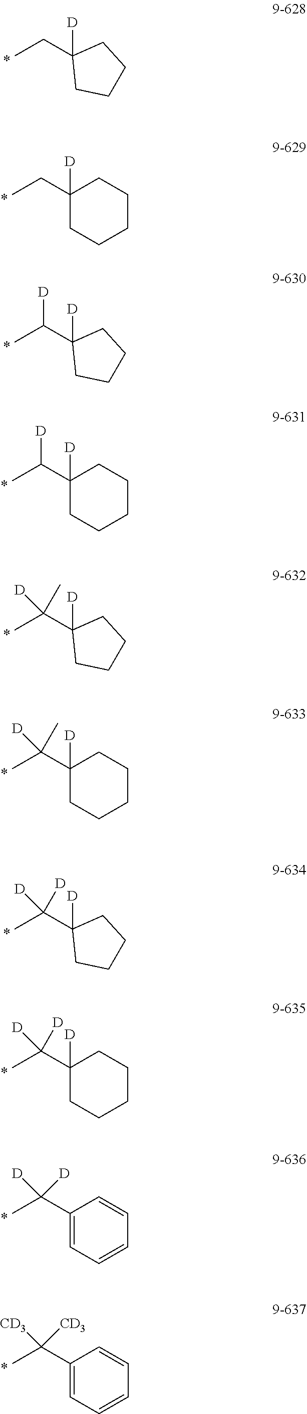

The “group represented by one of Formulae 9-1 to 9-39 in which at least one hydrogen is substituted with —F” and the “group represented by one of Formulae 9-201 to 9-230 in which at least one hydrogen is substituted with —F” may each be, for example, a group represented by one of Formulae 9-701 to 9-710:

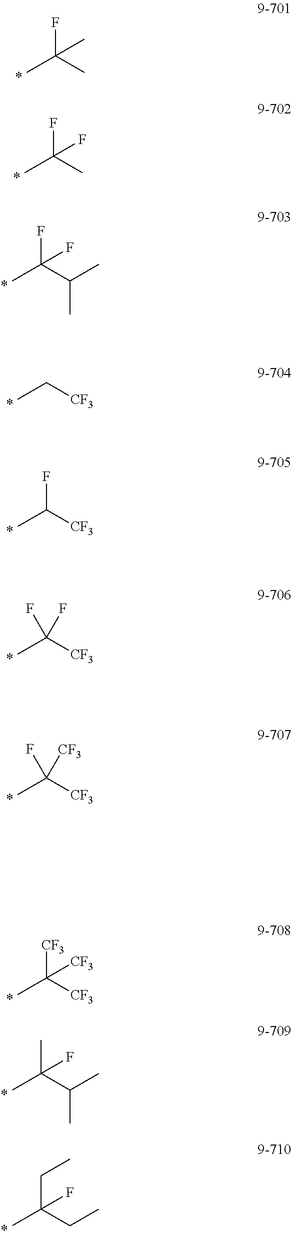

The “group represented by one of Formulae 10-1 to 10-145 in which at least one hydrogen is substituted with a deuterium” and the “group represented by one of Formulae 10-201 to 10-354 in which at least one hydrogen is substituted with deuterium” may each be, for example, a group represented by one of Formulae 10-501 to 10-553:

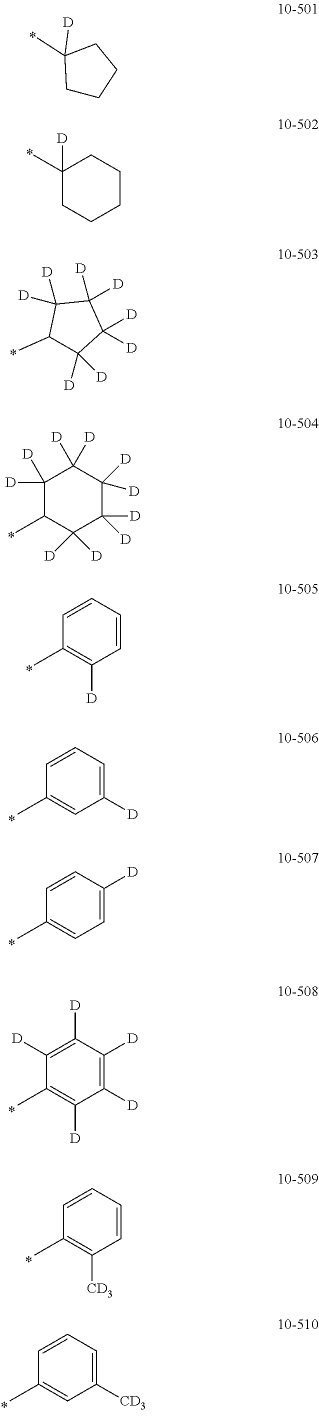

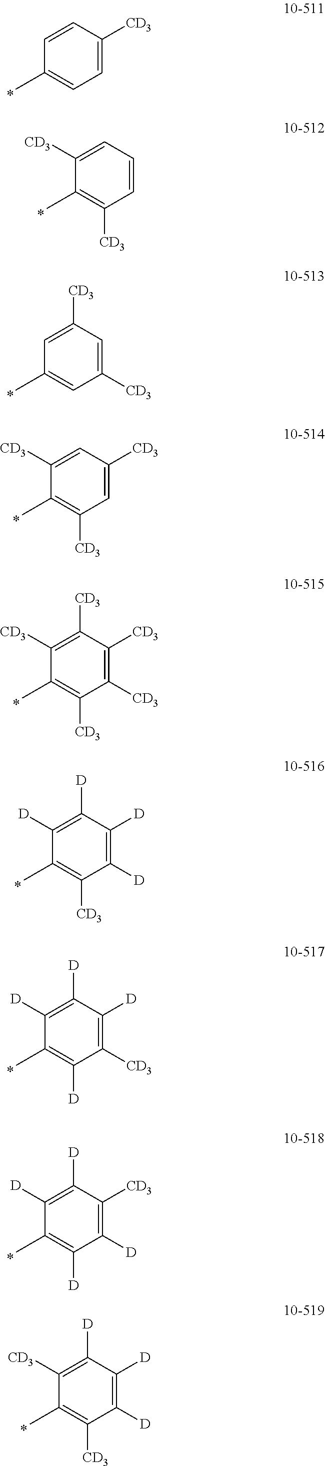

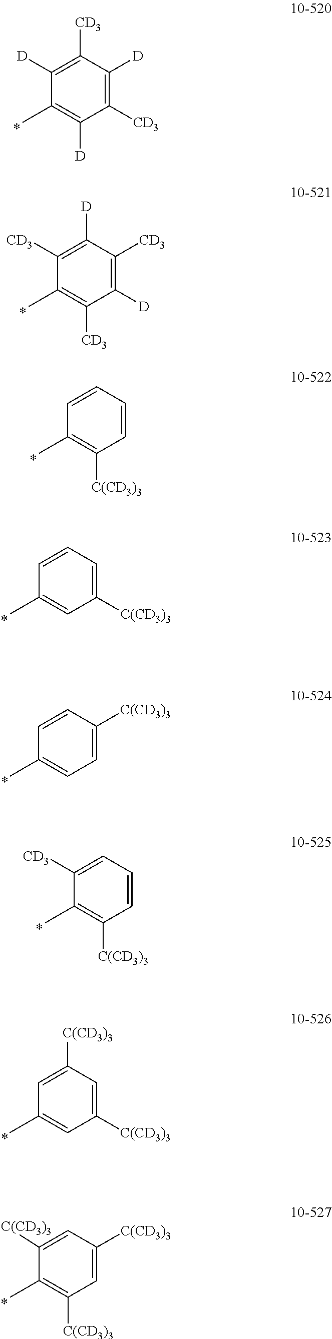

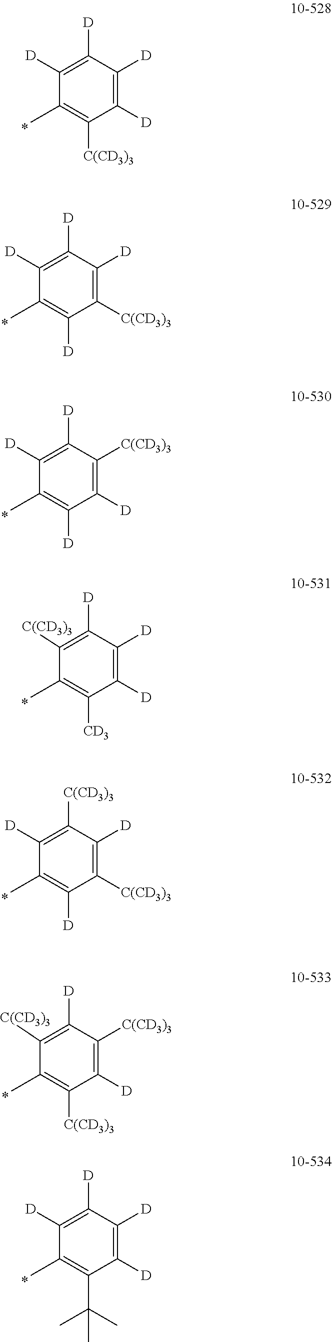

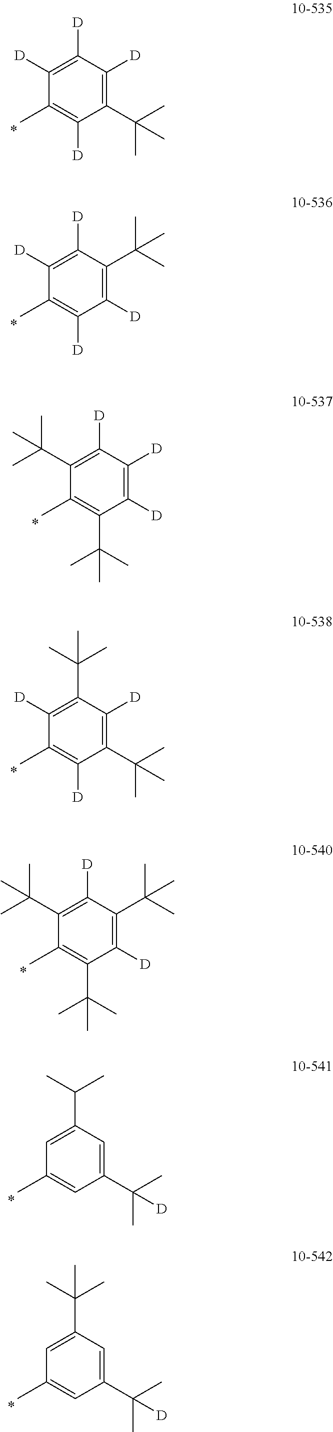

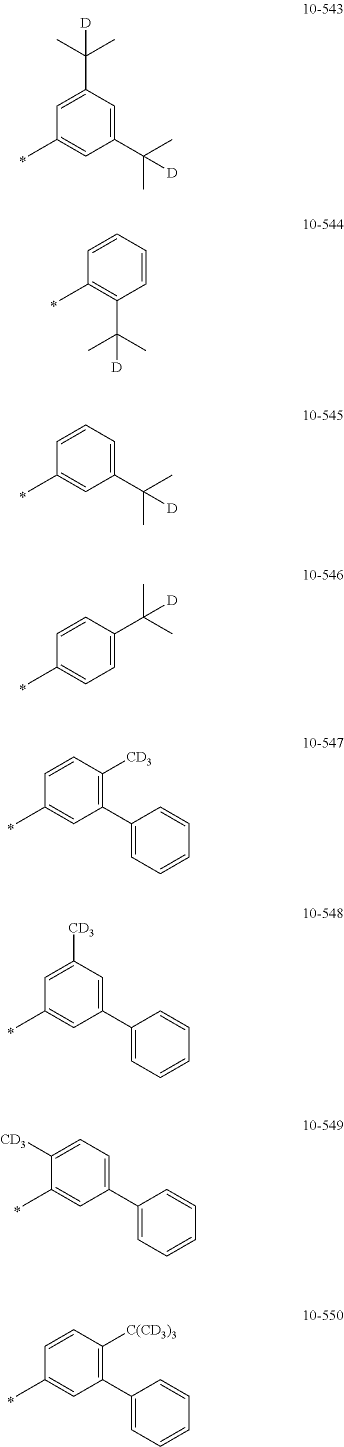

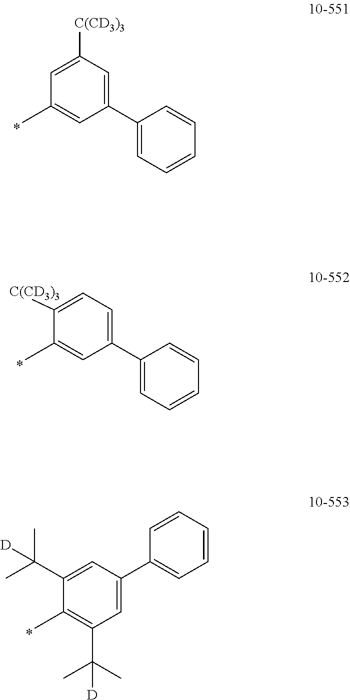

The “group represented by one of Formulae 10-1 to 10-145 in which at least one hydrogen is substituted with —F” and the “group represented by one of Formulae 10-201 to 10-354 in which at least one hydrogen is substituted with —F” may each be, for example, a group represented by one of Formulae 10-601 to 10-636:

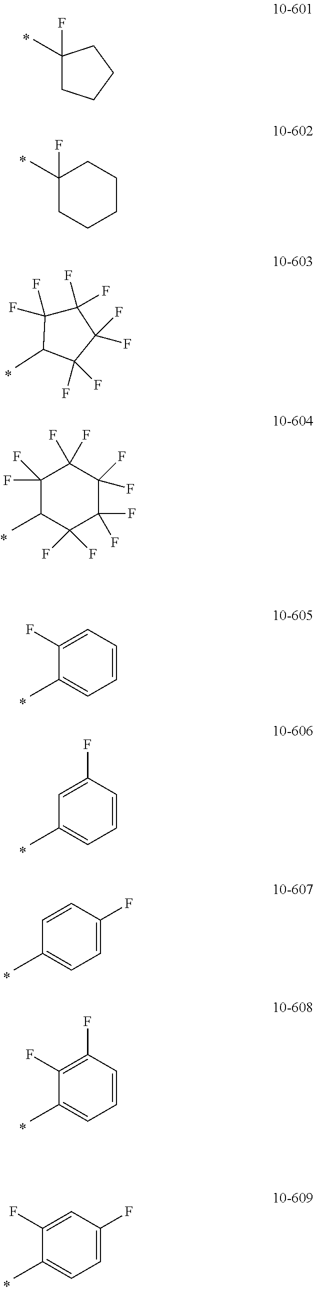

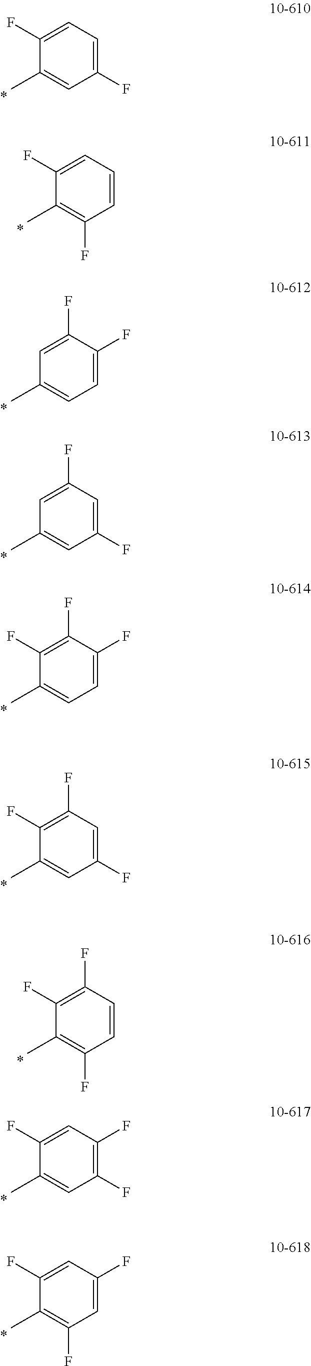

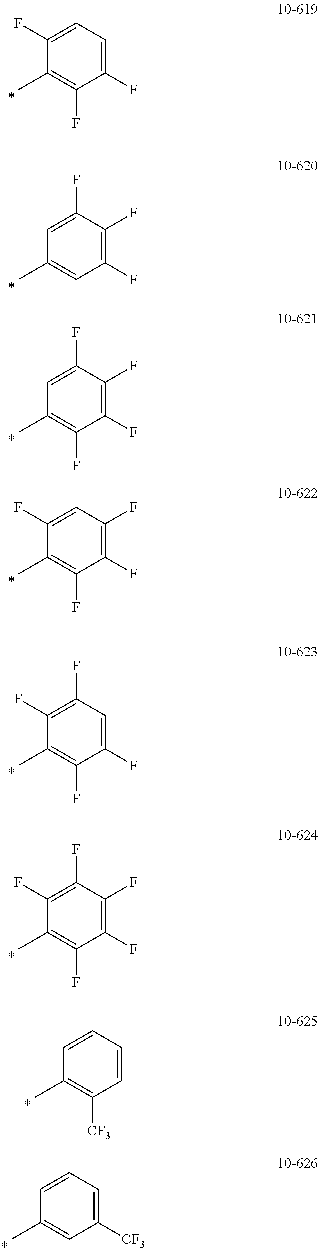

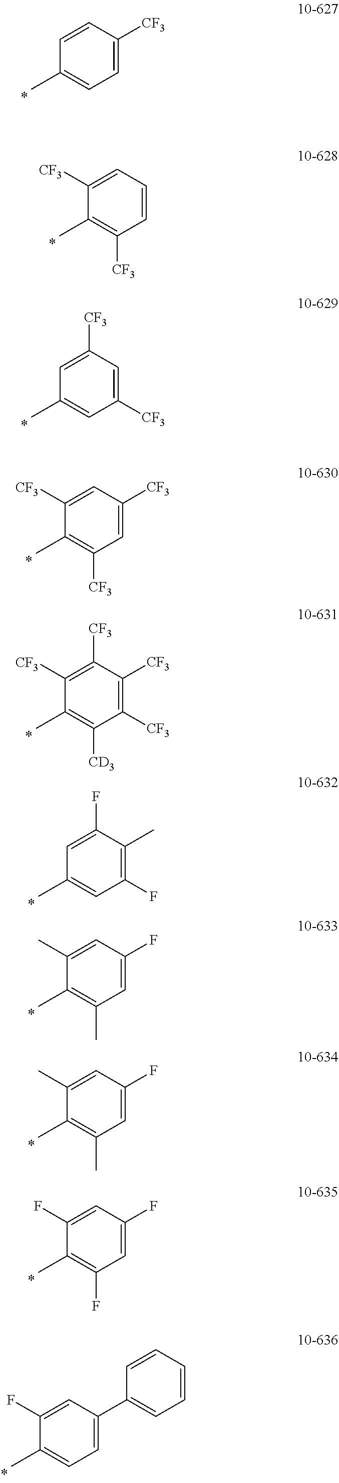

In Formulae 2 and 3, a2, b, and b2 indicate the number of R₂ groups, the number of Ze groups, and the number of Z₂ groups, respectively, wherein a2 may be an integer from 0 to 20 (for example, an integer from 0 to 10), b may be an integer 0 to 5, and b2 may be an integer from 0 to 4. When a2 is 2 or more, two or more R₂ groups may be identical to or different from each other, when b1 is 2 or more, two or more Z₁ groups may be identical to or different from each other, and when b2 is 2 or more, two or more Z₂ groups may be identical to or different from each other.

In one or more embodiments, in Formula 3, Z₁ is not hydrogen and b2 may be an integer from 1 to 5.

In one or more embodiments, Z₂ in Formula 3 is not hydrogen and b2 may be an integer from 1 to 4.

In one or more embodiments, the organometallic compound represented by Formula 1 may include deuterium, —F, or a combination thereof.

In one or more embodiments, the organometallic compound represented by Formula 1 may satisfy at least one of Condition 1 to Condition 12:

### Condition 1

R₁₁ is not hydrogen, and includes at least one deuterium.

### Condition 2

At least one of R₁₁ to R₁₃ is not hydrogen, and includes at least one deuterium.

### Condition 3

At least one of R₂ groups in the number of a2 is not hydrogen, and includes at least one deuterium.

### Condition 4

L₃ is not a single bond, and includes at least one deuterium.

### Condition 5

Z₃ is not hydrogen, and includes at least one deuterium.

### Condition 6

At least one of Z₁ group in the number of b1 is not hydrogen, and includes at least one deuterium.

### Condition 7

R₁₁ is not hydrogen and includes at least one fluoro group (—F).

### Condition 8

at least one of R₁₁ to R₁₃ is not hydrogen and includes at least one fluoro group.

### Condition 9

at least one of R₂ group in the number of a2 is not hydrogen and includes at least one fluoro group.

### Condition 10

L₃ is not a single bond and may include at least one fluoro group.

### Condition 11

Z₃ is not hydrogen and includes at least one fluoro group.

### Condition 12

at least one of Z₁ group in the number of b1 is not hydrogen and includes at least one fluoro group.

In Formulae 2 and 3, i) R₁₁ and R₁₂ may optionally be linked to each other to form a C₅-C₃₀ carbocyclic group that is unsubstituted or substituted with at least one R₁₀ₐ or a C₁-C₃₀ heterocyclic group that is unsubstituted or substituted with at least one R₁₀ₐ, ii) two or more of a plurality of R₂ groups may optionally be linked to form a C₅-C₃₀ carbocyclic group that is unsubstituted or substituted with at least one R₁₀ₐ, or two or more of a plurality of R₂ groups may optionally be linked to form a C₁-C₃₀ heterocyclic group that is unsubstituted or substituted with at least one R₁₀ₐ, iii) two or more of a plurality of Z₁ groups may optionally be linked to each other to form a C₅-C₃₀ carbocyclic group that is unsubstituted or substituted with at least one R₁₀ₐ, or two or more of a plurality of Z₁ groups may optionally be linked to each other to form a C₁-C₃₀ heterocyclic group that is unsubstituted or substituted with at least one R₁₀ₐ, or iv) two or more of a plurality of Z₂ groups may optionally be linked to each other to form a C₅-C₃₀ carbocyclic group that is unsubstituted or substituted with at least one R₁₀ₐ, or two or more of a plurality of Z₂ groups may optionally be linked to each other to form a C₁-C₃₀ heterocyclic group that is unsubstituted or substituted with at least one R₁₀ₐ. R₁₀ₐ may be understood by referring to the description provided in connection with Z₁. For example, R₁₀ₐ may be understood by referring to the description provided in connection with Z₁, but may not be hydrogen.

In Formulae 2 and 3, * and *′ each indicate a binding site to a neighboring atom.

In one or more embodiments, a group represented by:

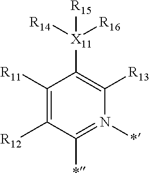

in Formula 2 may be a group represented by Formula 2-1 or 2-2:

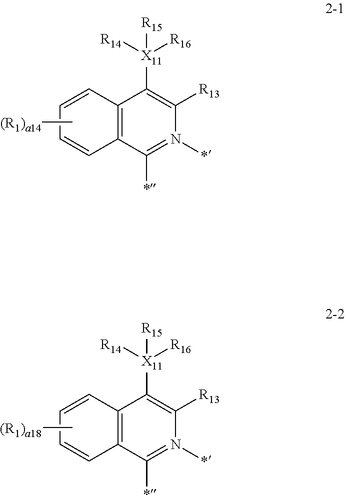

In Formulae 2-1 and 2-2,
X₁₁, and R₁₃ to R₁₆ may each be understood by referring to the corresponding descriptions thereof provided herein,
R₁ may be understood by referring to the description provided in connection with R₁₂,
a14 may be an integer from 0 to 4,
a18 may be an integer from 0 to 8,
*′ indicates a binding site to M in Formula 1, and
*″ indicates a binding site to a neighboring atom in Formula 2.

In one or more embodiments, a group represented by:

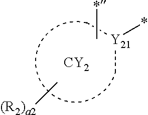

in Formula 2 may be a group represented by one of Formulae CY2-1 to CY2-33:

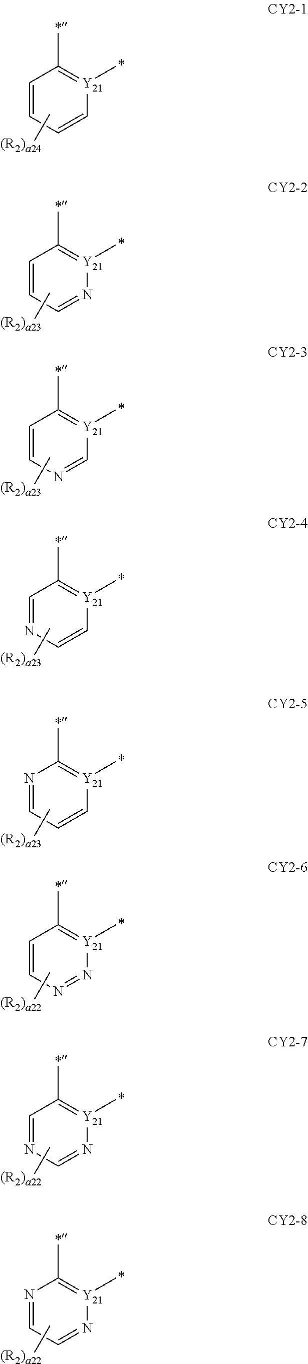

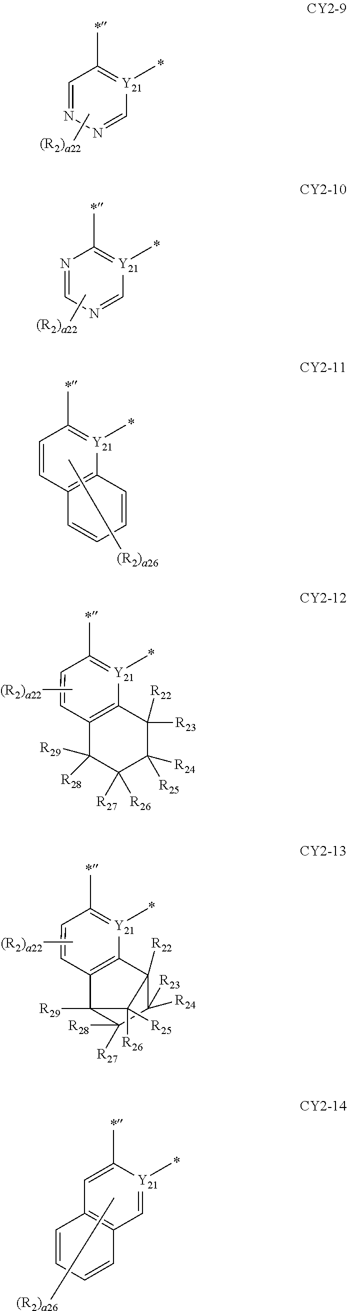

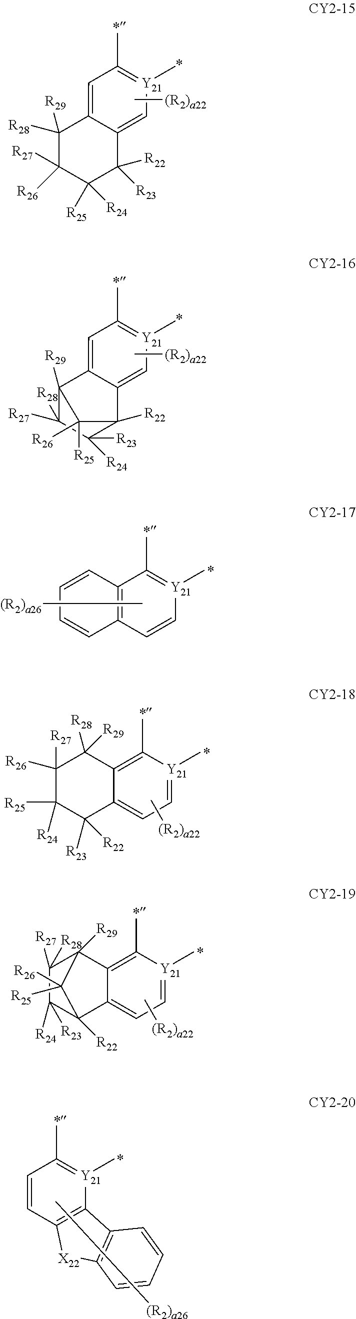

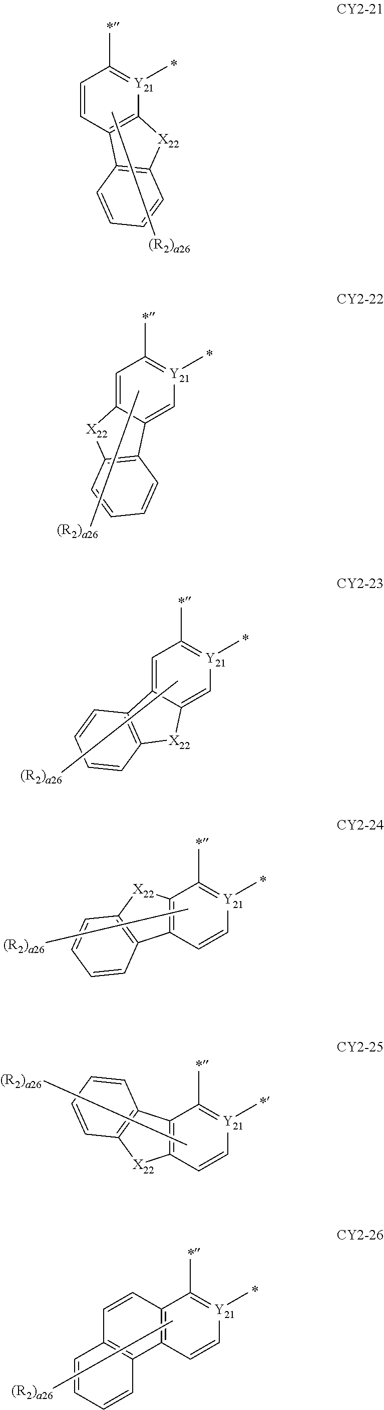

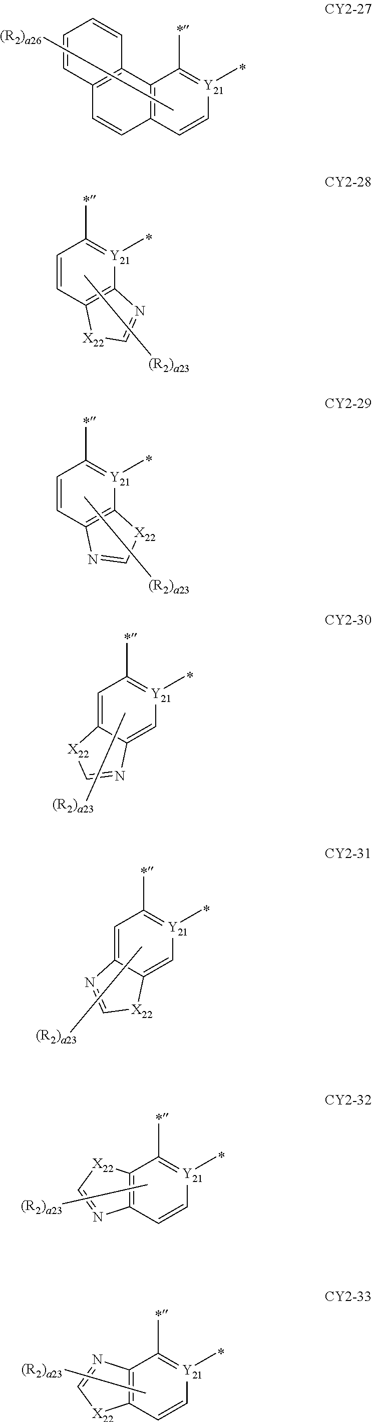

In Formulae CY2-1 to CY2-33,
Y₂₁ and R₂ may each be understood by referring to the descriptions thereof provided herein,
X₂₂ may be C(R₂₂)(R₂₃), N(R₂₂), O, S, or Si(R₂₂)(R₂₃),
R₂₂ to R₂₉ may each independently a substituent group understood by referring to the description provided in connection with R₂,
a28 may be an integer from 0 to 8,
a26 may be an integer from 0 to 6,
a24 may be an integer from 0 to 4,
a23 may be an integer from 0 to 3,
a22 may be an integer from 0 to 2,
*″ indicates a binding site to a neighboring atom in Formula 2, and
* indicates a binding site to M in Formula 1.

In one or more embodiments, a group represented by:

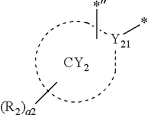

in Formula 2 may be a group represented by one of Formulae CY2(1) to CY2(56) or a group represented by one of Formulae CY2-11 to CY2-33:

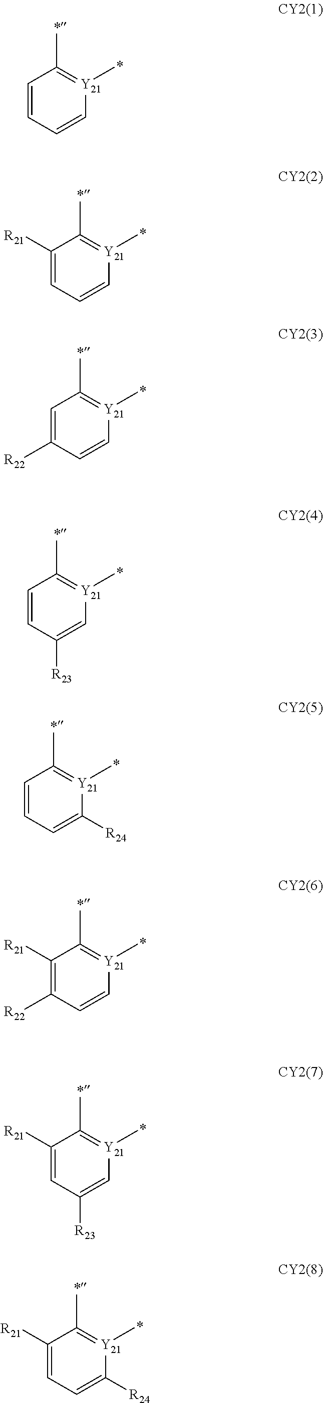

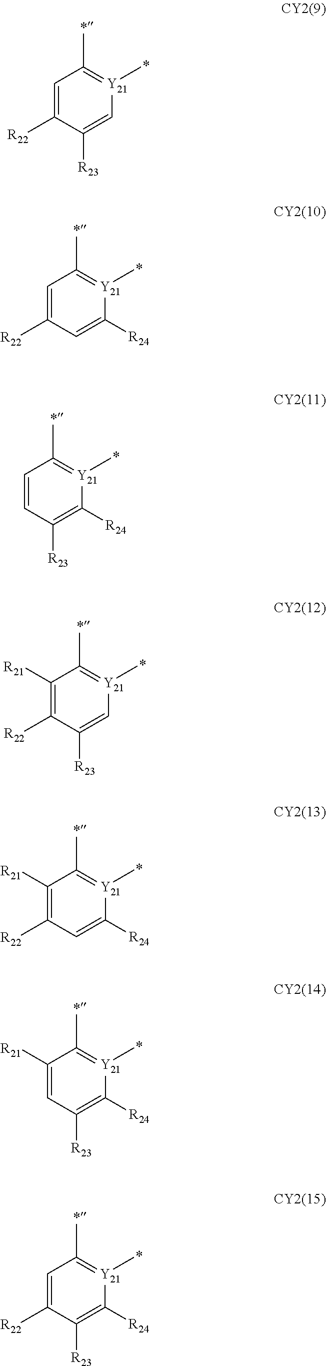

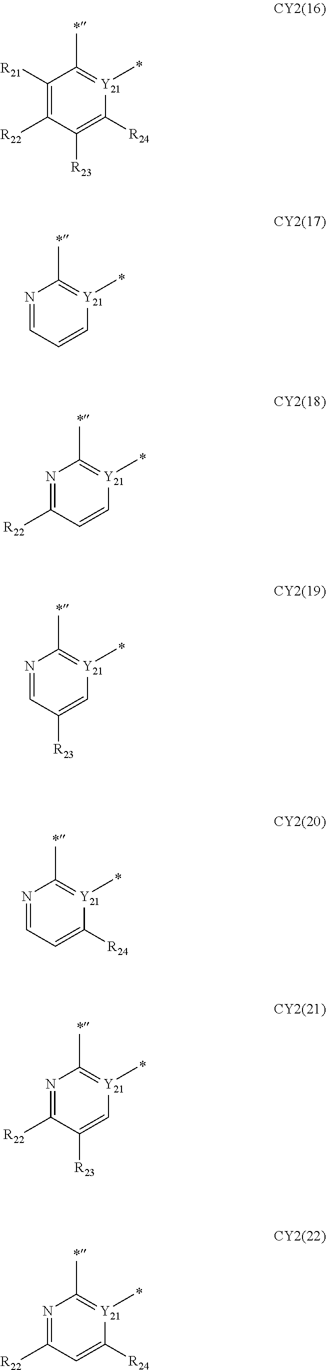

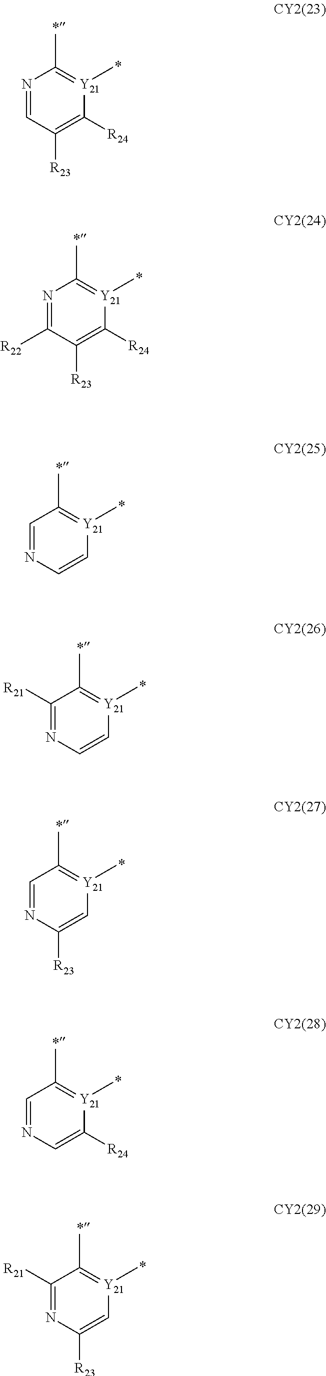

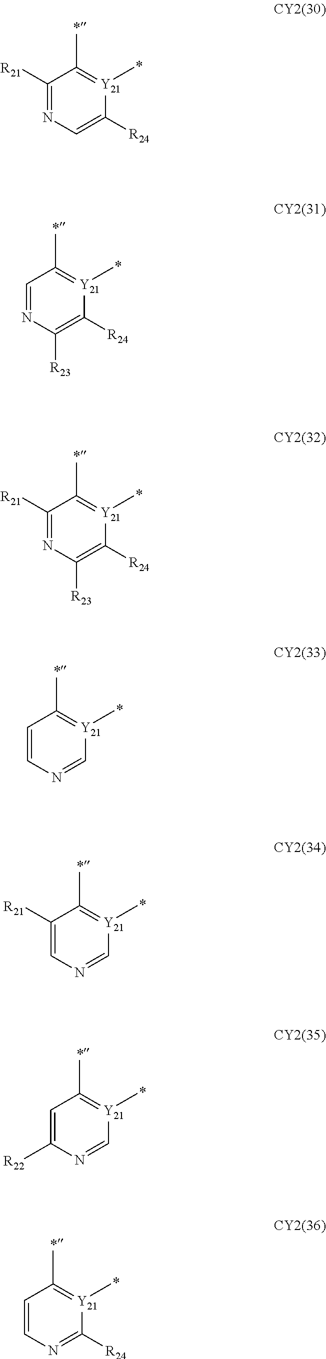

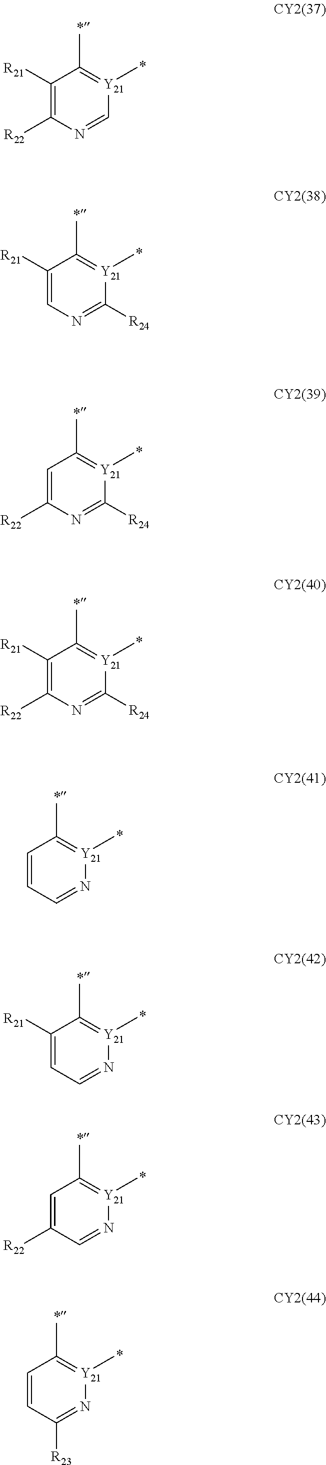

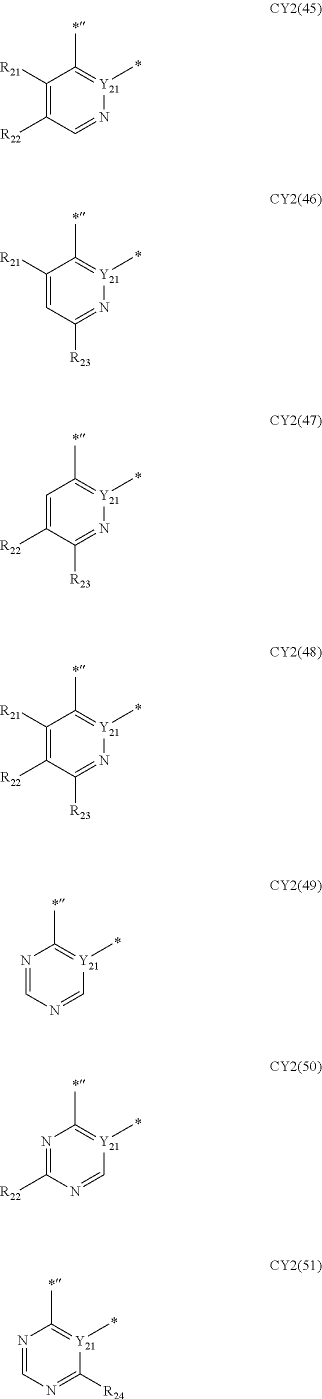

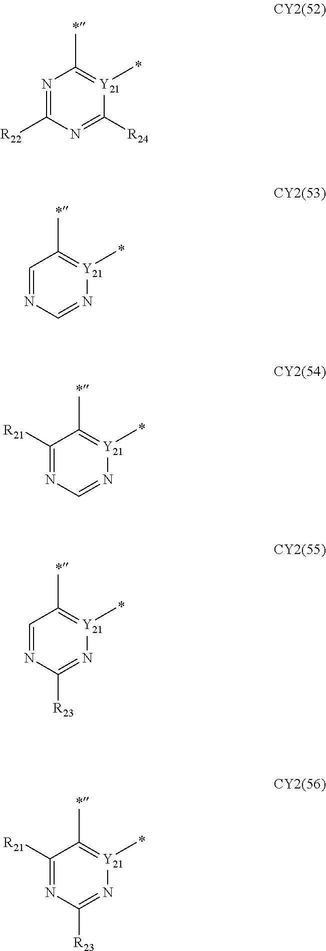

In Formulae CY2(1) to CY2(56),
Y₂₁ may be C,
R₂₁ to R₂₄ may each independently be understood by referring to the description provided in connection with R₂, wherein each of R₂₁ to R₂₄ may not be hydrogen,
*″ indicates a binding site to a neighboring atom in Formula 2, and
*indicates a binding site to M in Formula 1.

In one or more embodiments, a group represented by:

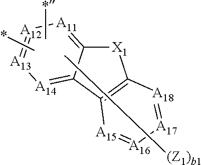

in Formula 3 may be a group represented by one of Formulae CY3-1 to CY3-6:

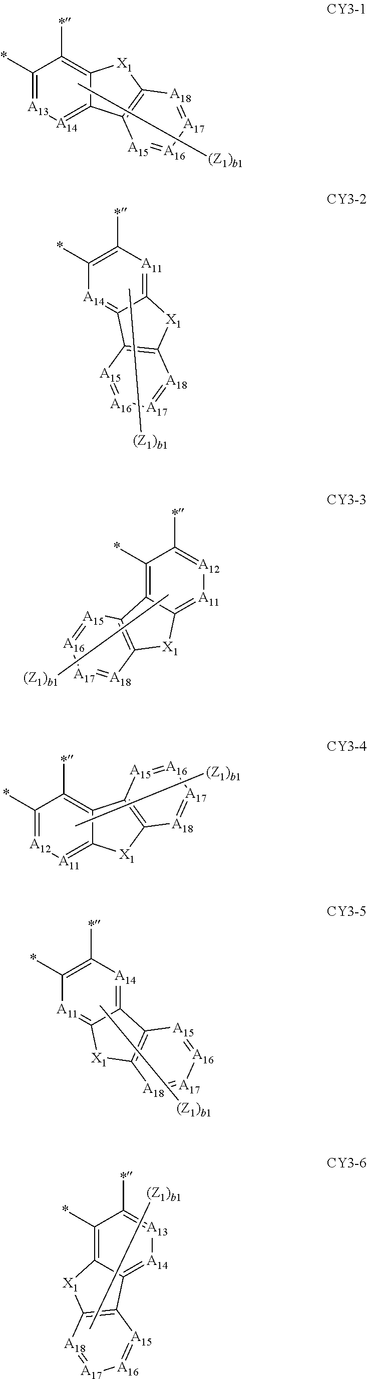

In Formulae CY3-1 to CY3-6,
X₁, Z₁ and b1 may each be understood by referring to the corresponding descriptions thereof provided herein,
A₁₁ to A₁₈ may each independently be C or N, wherein at least one of A₁₃ to A₁₈ in Formulae CY3-1 and CY3-6 may be N, at least one of A₁₁, A₁₄, A₁₆, A₁₆, A₁₇ and A₁₈ in Formulae CY3-2 and CY3-5 may be N, and at least one of A₁₁, A₁₂, A₁₅, A₁₆, A₁₇ and A₁₈ in Formulae CY3-3 and CY3-4 may be N,
* indicates a binding site to M in Formula 1, and
*″ indicates a binding site to a neighboring atom in Formula 3.

In one or more embodiments, a group represented by:

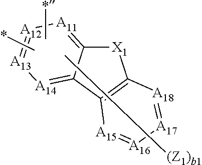

in Formula 3 may be a group represented by one of Formulae CY3-1-1 to CY3-1-6, CY3-2-1 to CY3-2-6, CY3-3-1 to CY3-3-6, CY3-4-1 to CY3-4-6, CY3-5-1 to CY3-5-6, and CY3-6-1 to CY3-6-6:

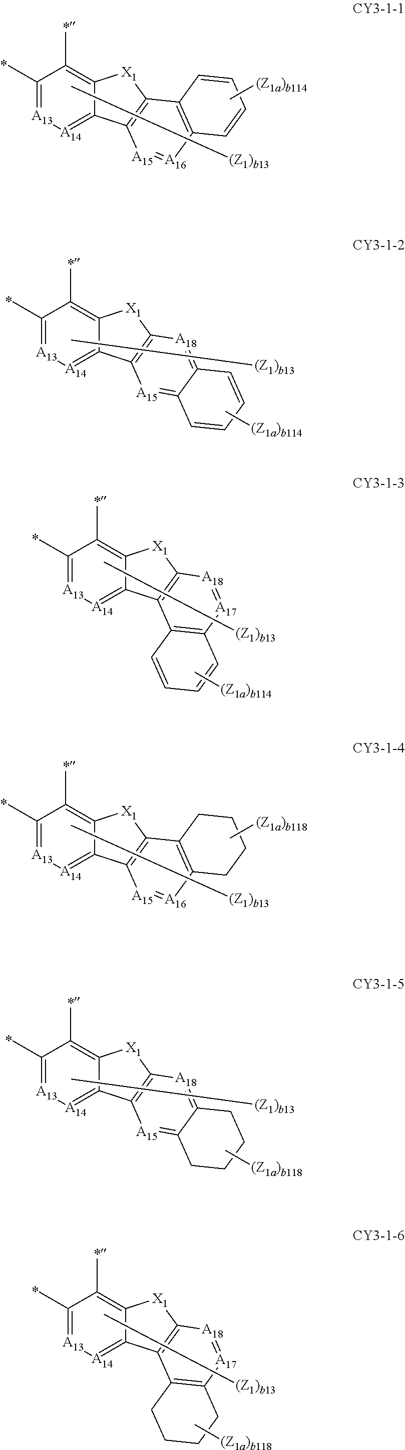

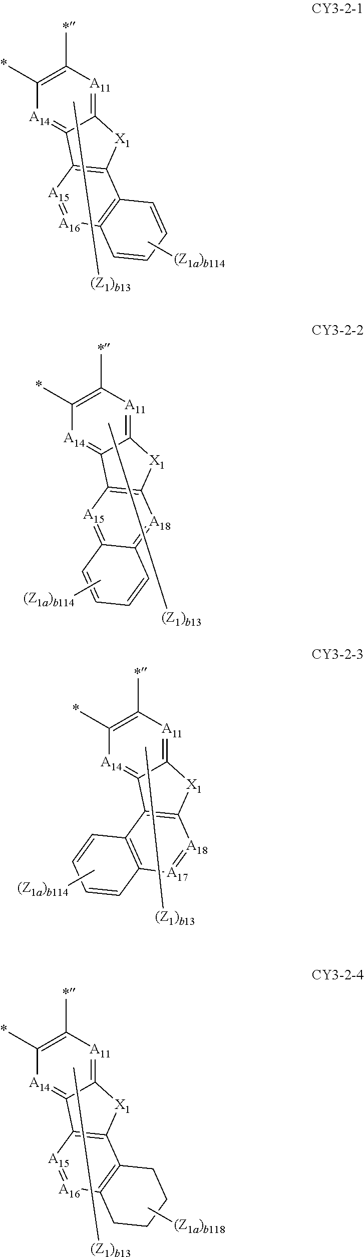

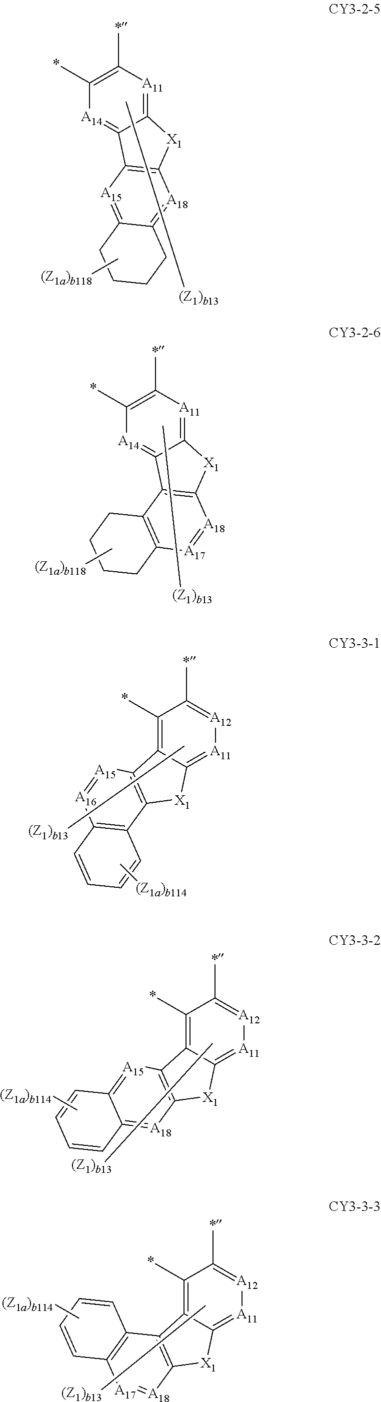

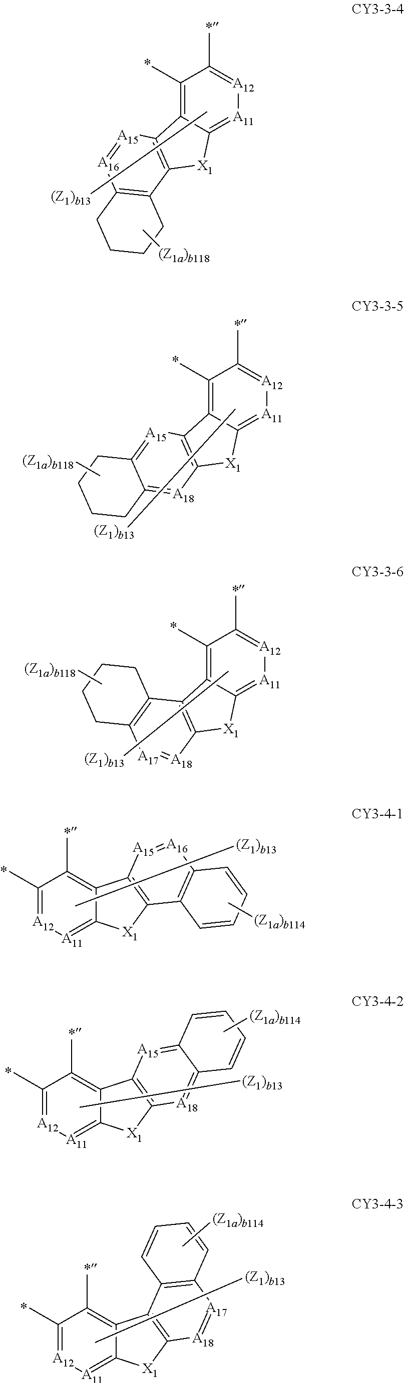

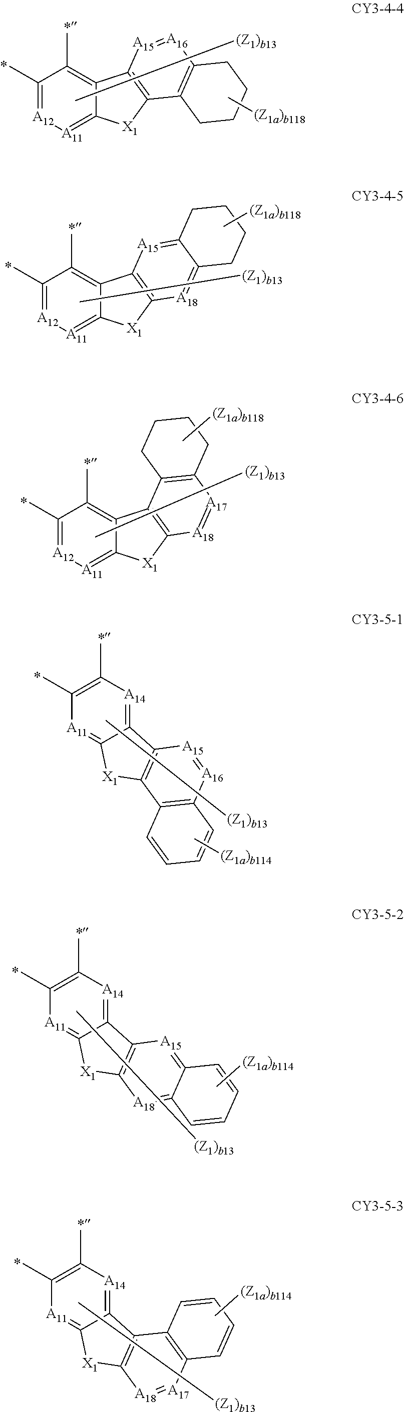

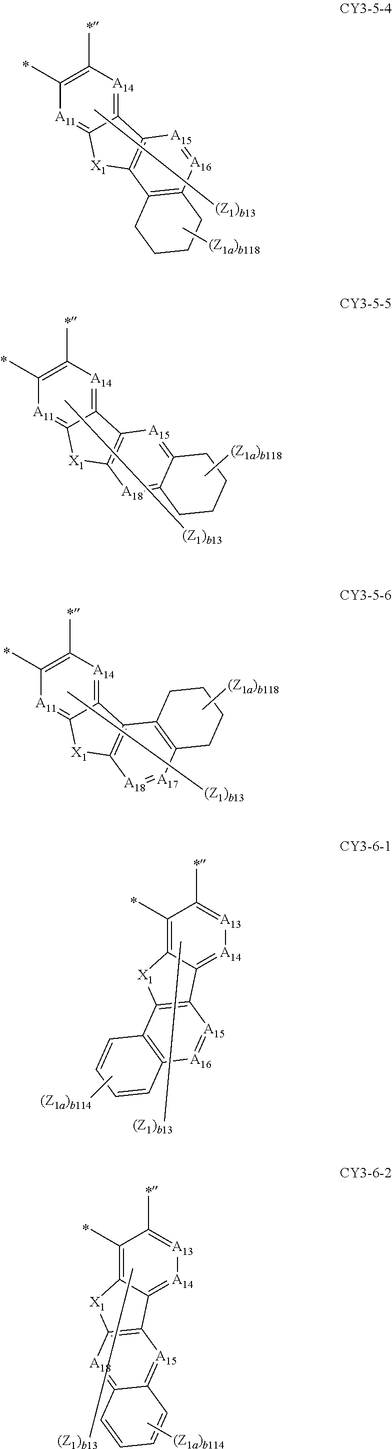

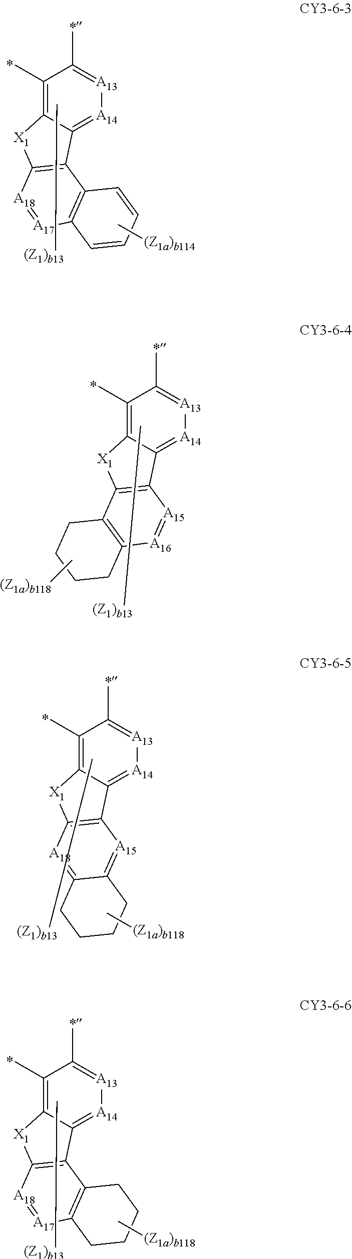

In Formulae CY3-1-1 to CY3-1-6, CY3-2-1 to CY3-2-6, CY3-3-1 to CY3-3-6, CY3-4-1 to CY3-4-6, CY3-5-1 to CY3-5-6, and CY3-6-1 to CY3-6-6,
X₁ and Z₁ may each be understood by referring to the corresponding descriptions thereof provided herein,
Z₁ₐ may be understood by referring to the description provided in connection with R₁ₐ,
A₁₁ to A₁₈ may each independently be C or N, wherein a) at least one of A₁₃, A₁₄, A₁₅, and A₁₆ in Formulae CY3-1-1, CY3-1-4, CY3-6-1, and CY3-6-4 is N, b) at least one of A₁₃, A₁₄, A₁₅, and A₁₈ in Formulae CY3-1-2, CY3-1-5, CY3-6-2, and CY3-6-5 is N, c) at least one of A₁₃, A₁₄, A₁₇, and A₁₈ in Formulae CY3-1-3, CY3-1-6, CY3-6-3, and CY3-6-6 is N, d) at least one of A₁₁, A₁₄, A₁₅, and A₁₆ in Formulae CY3-2-1, CY3-2-4, CY3-5-1, and CY3-5-4 is N, e) at least one of A₁₁, A₁₄, A₁₅, and A₁₈ in Formulae CY3-2-2, CY3-2-5, CY3-5-2, and CY3-5-5 is N, f) at least one of A₁₁, A₁₄, A₁₇, and A₁₈ in Formulae CY3-2-3, CY3-2-6, CY3-5-3, and CY3-5-6 is N, g) at least one of A₁₁, A₁₂, A₁₅, and A₁₆ in Formulae CY3-3-1, CY3-3-4, CY3-4-1, and CY3-4-4 is N, h) at least one of A₁₁, A₁₂, A₁₅ and A₁₈ in Formulae CY3-3-2, CY3-3-5, CY3-4-2, and CY3-4-5 is N, i) at least one of A₁₁, A₁₂, A₁₇, and A₁₈ in Formulae CY3-3-3, CY3-3-6, CY3-4-3, and CY3-4-6 is N,
b13 may be an integer from 0 to 3,
b114 may be an integer from 0 to 4,
b118 may be an integer from 0 to 8,
* indicates a binding site to M in Formula 1, and
*″ indicates a binding site to a neighboring atom in Formula 3.

In one or more embodiments, a group represented by:

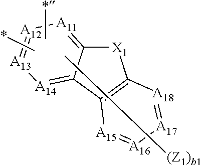

in Formula 3 may be a group represented by one of Formulae NCY3(1) to NCY3(84):

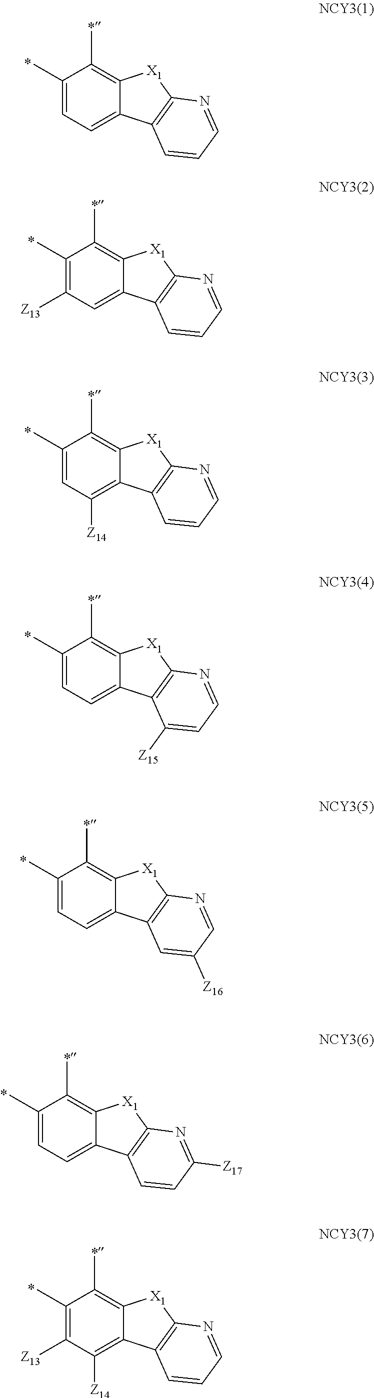

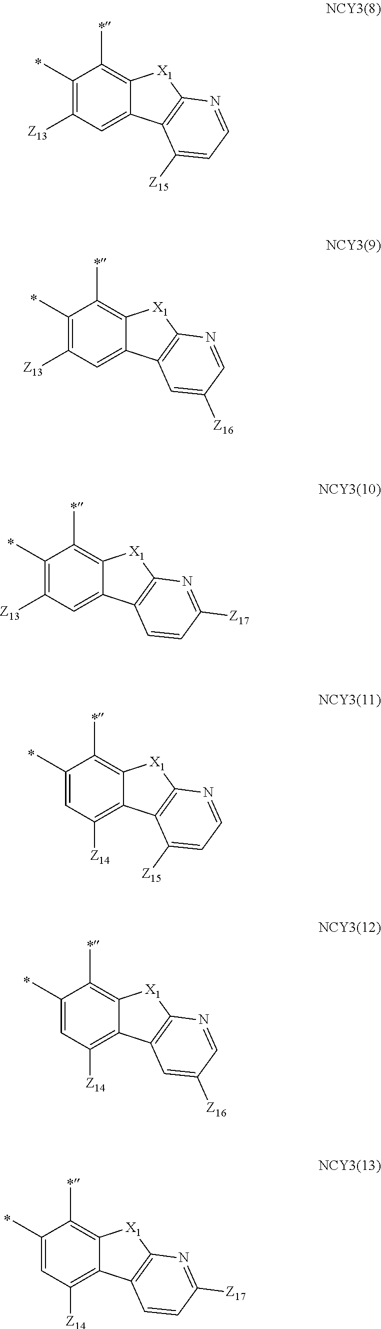

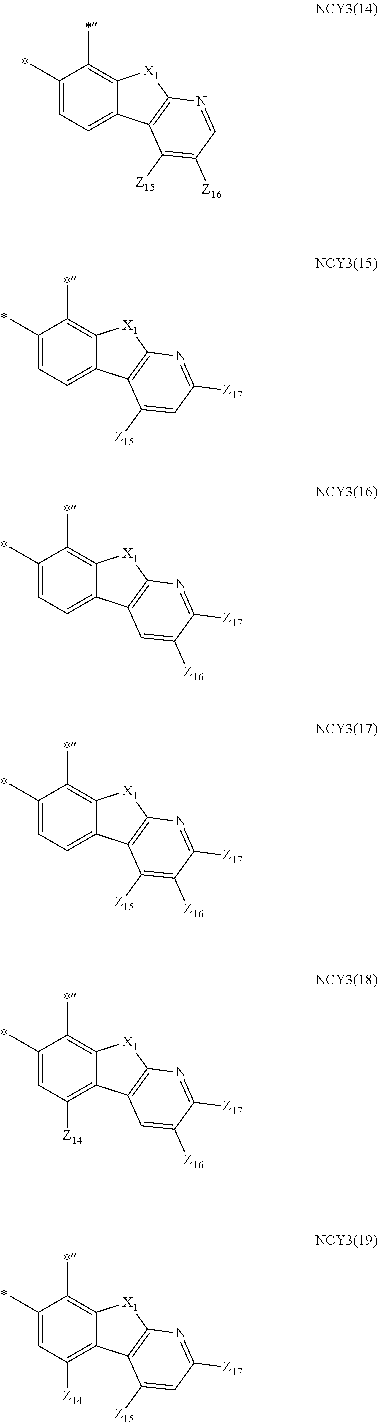

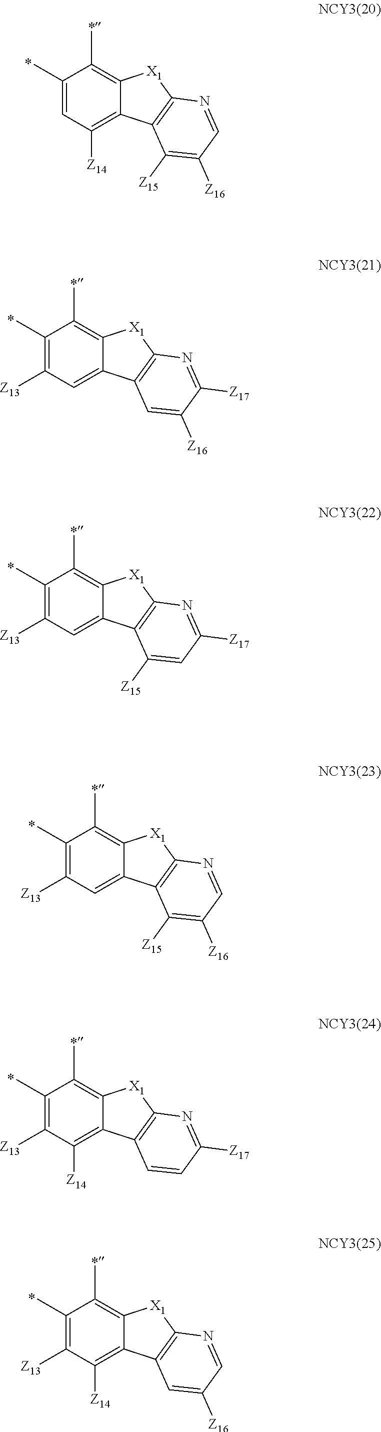

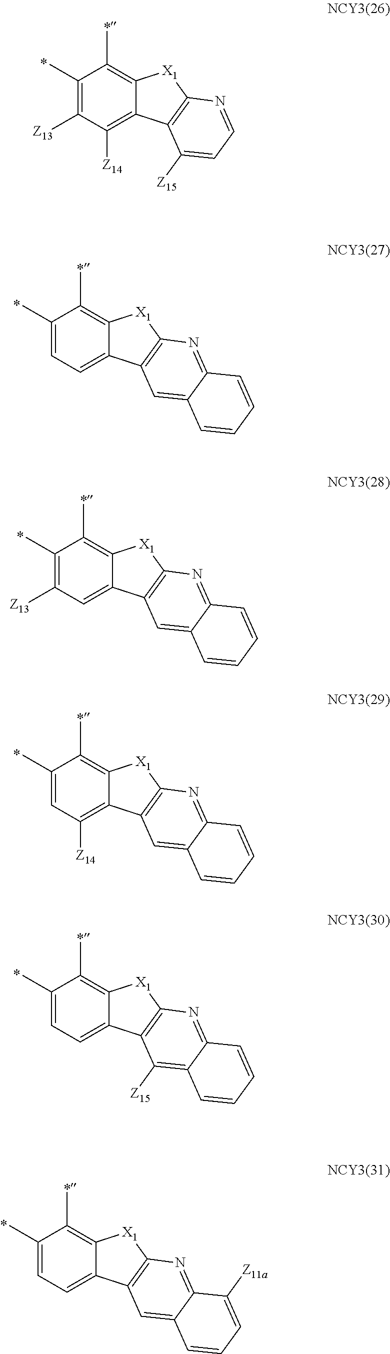

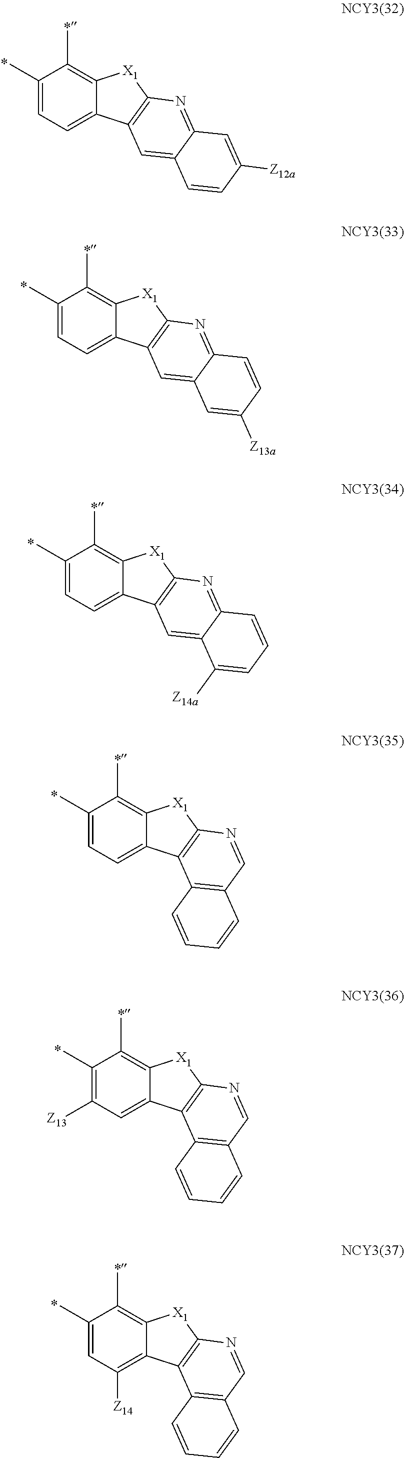

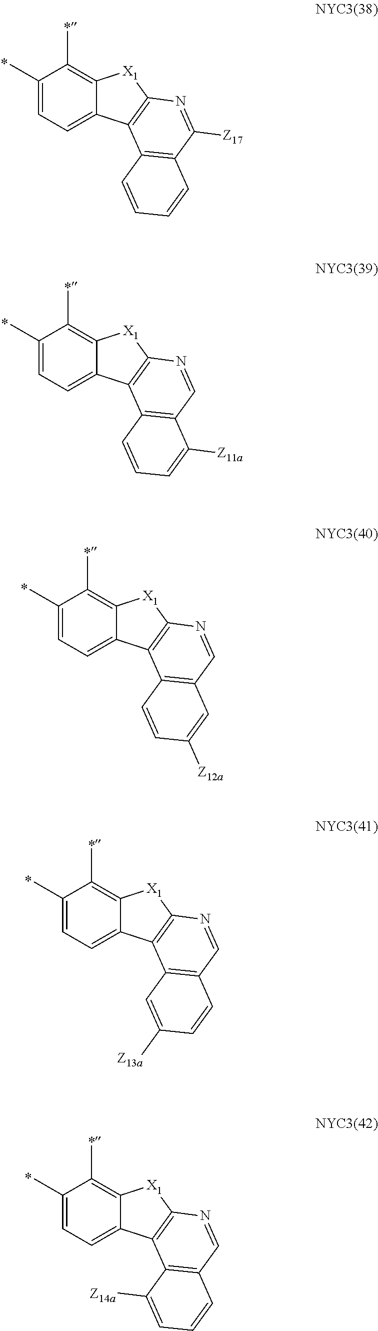

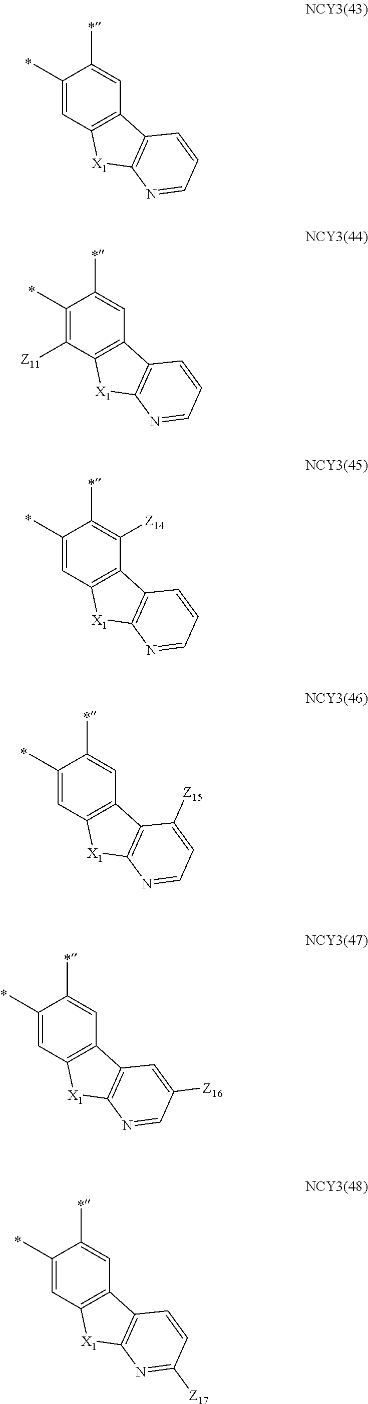

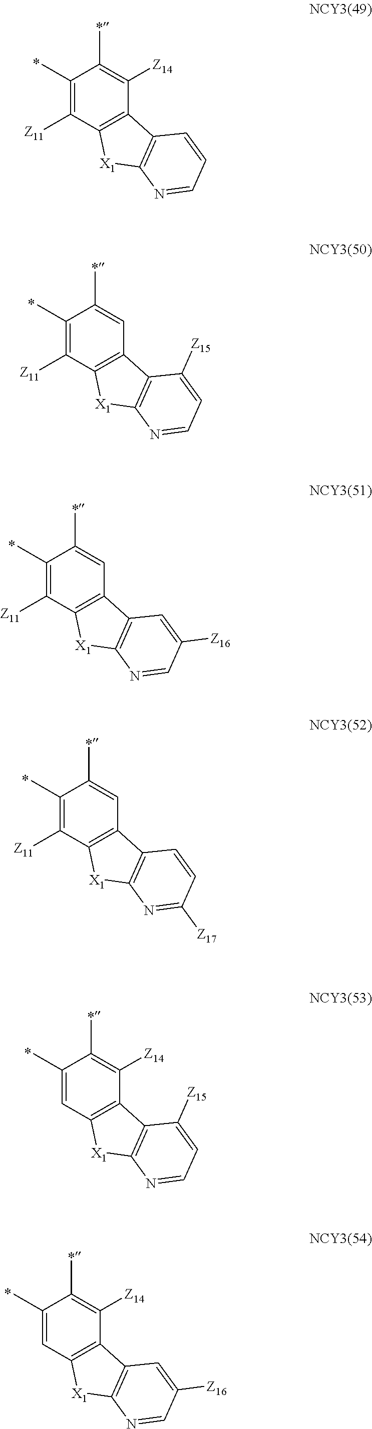

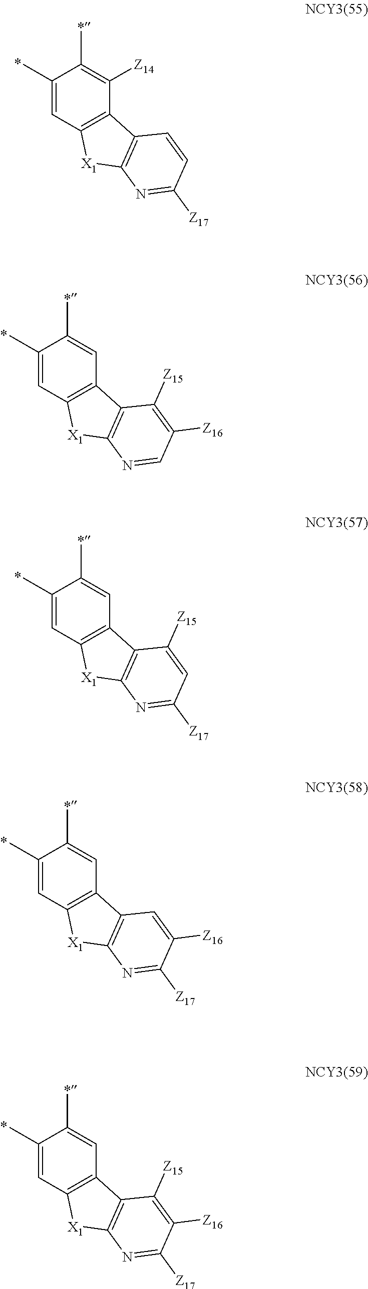

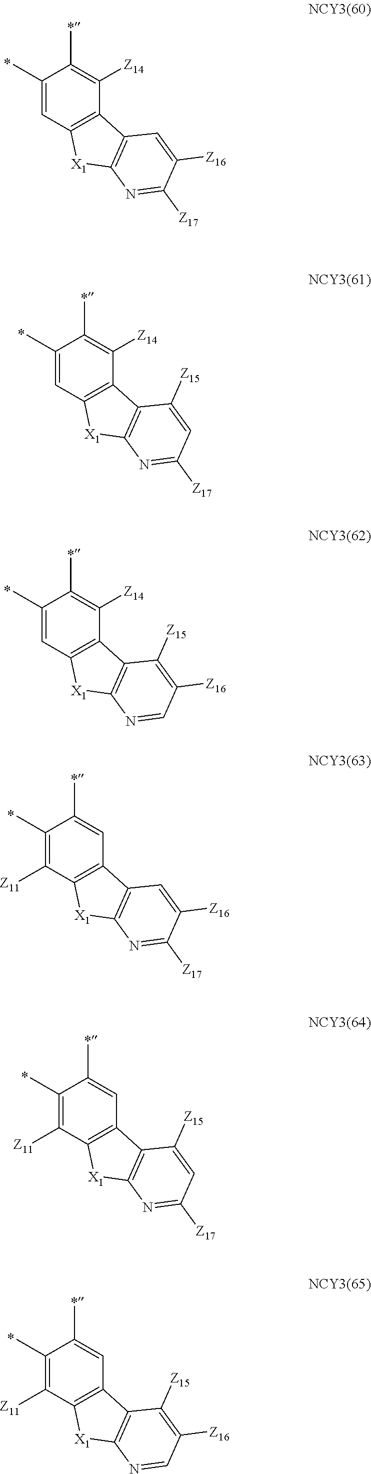

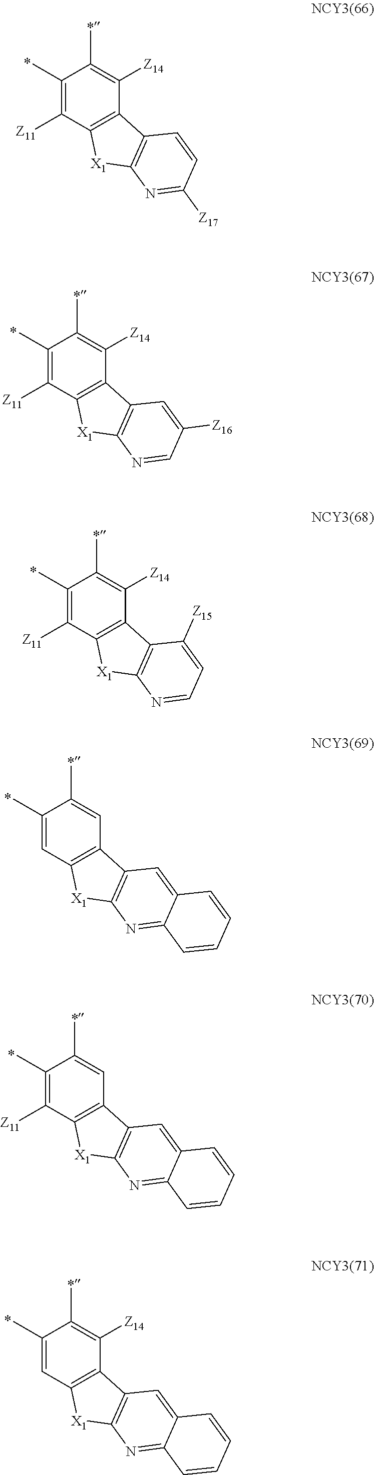

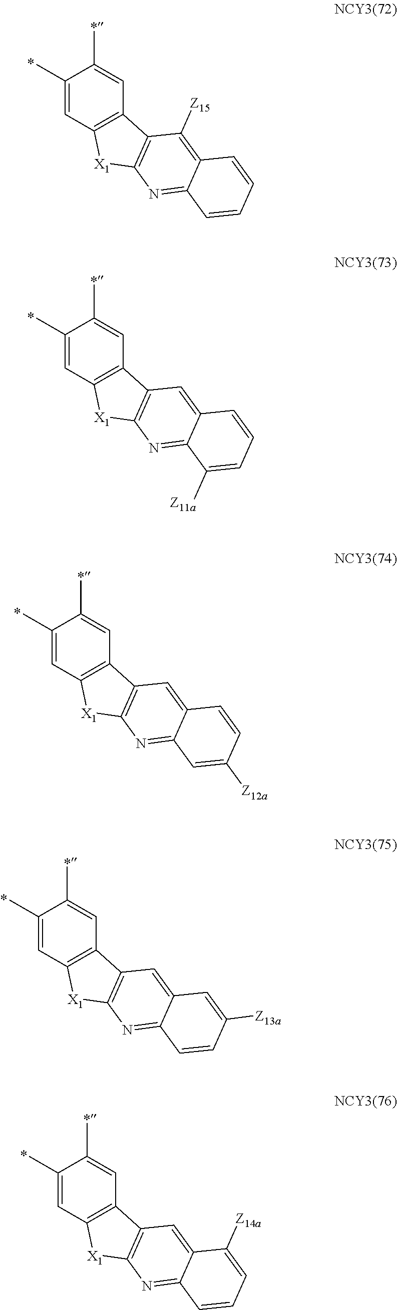

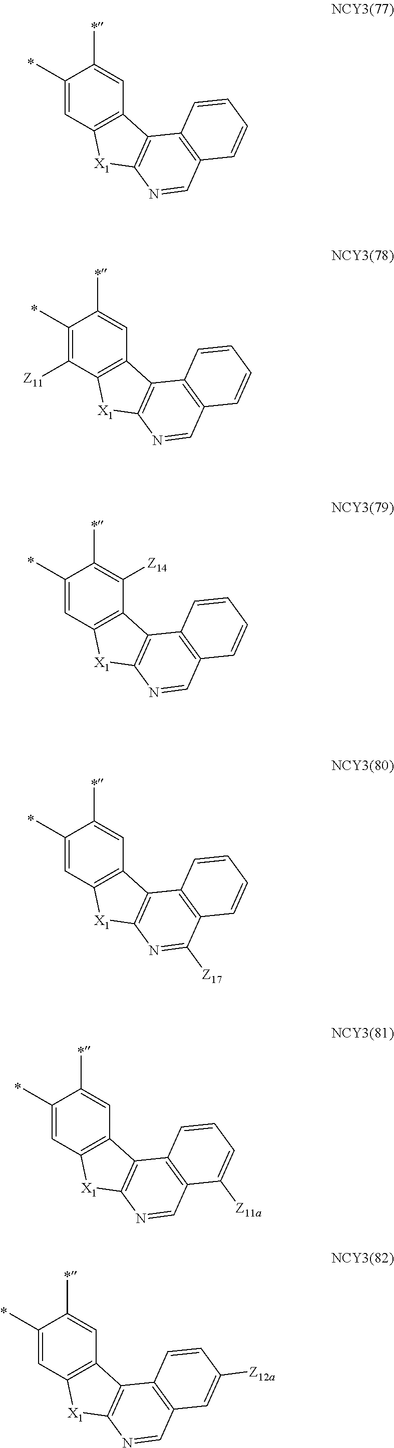

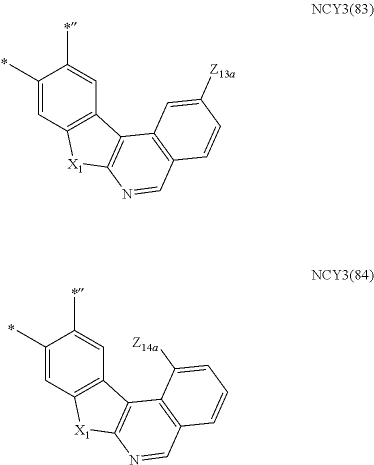

In Formulae NCY3(1) to NCY3(84),
X₁ may be understood by referring to the corresponding descriptions thereof provided herein,
Z₁₁ to Z₁₈ and Z₁₁a to Z₁₄a may be each understood by referring to the description provided in connection with Z₁, and each of Z₁₁ to Z₁₈ and Z₁₁a to Z₁₄a is not hydrogen,
*indicates a binding site to M in Formula 1, and
*″ indicates a binding site to a neighboring atom in Formula 3.

In one or more embodiments, a group represented by:

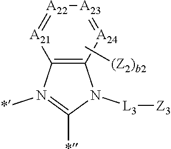

in Formula 3 may be a group represented by one of Formulae CY4-1 to CY4-60:

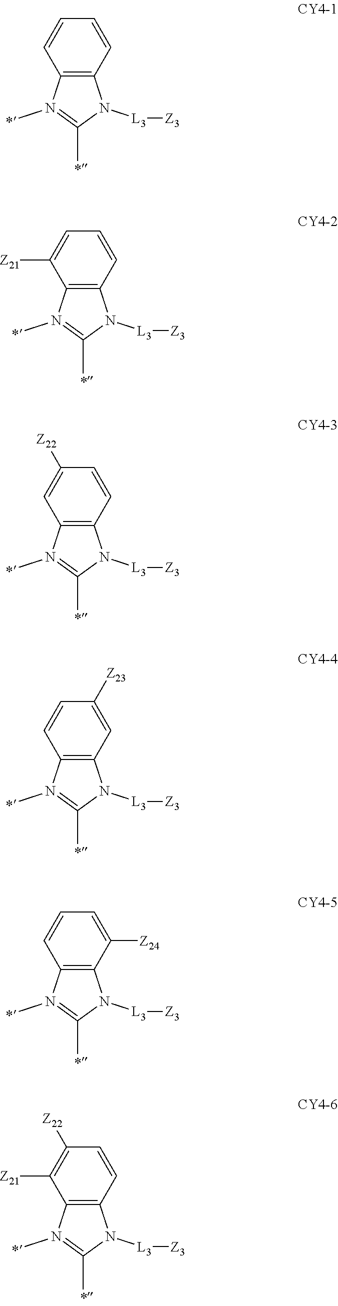

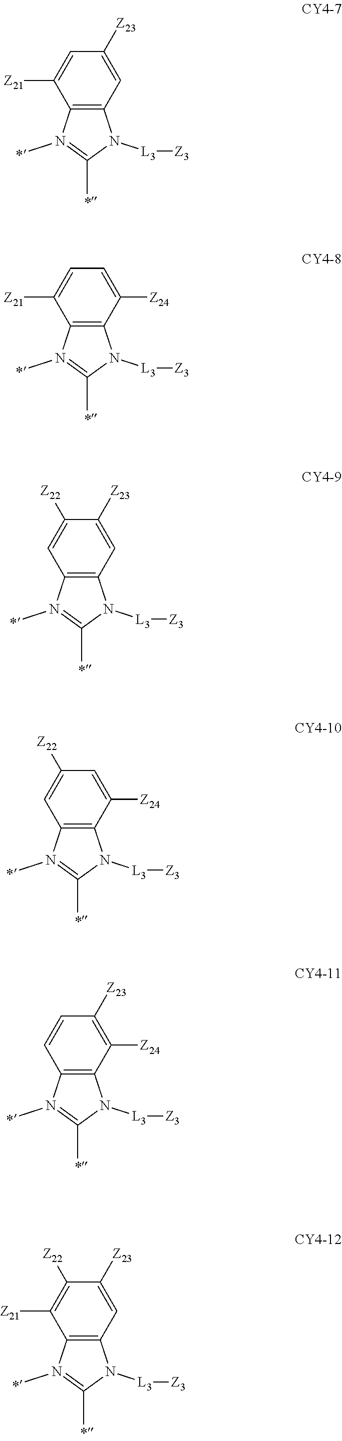

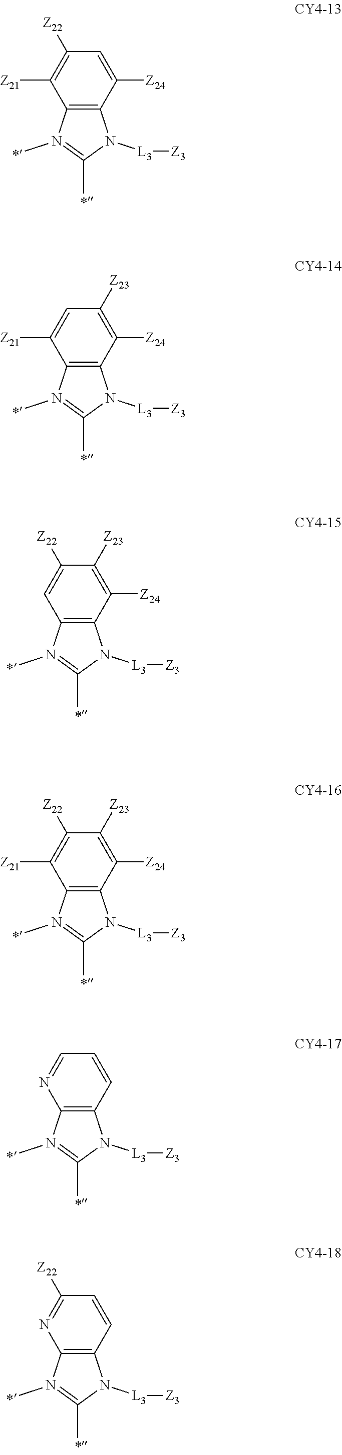

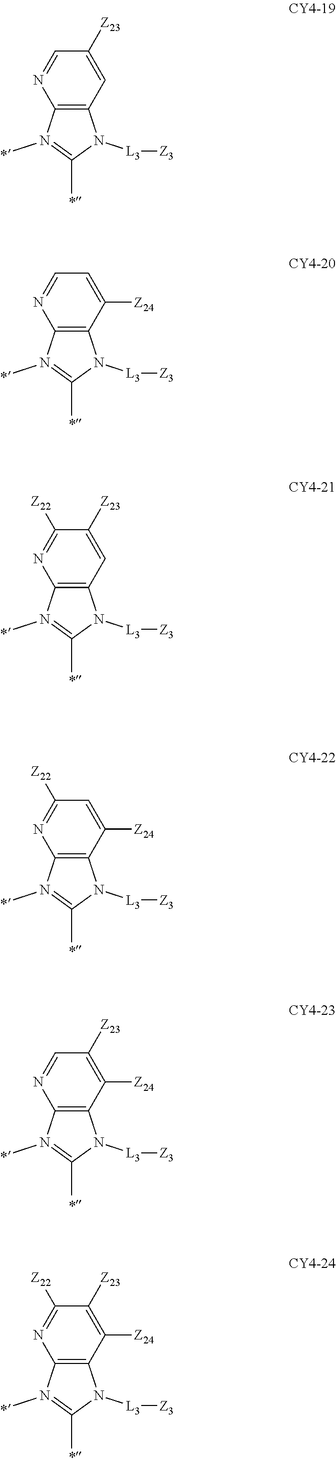

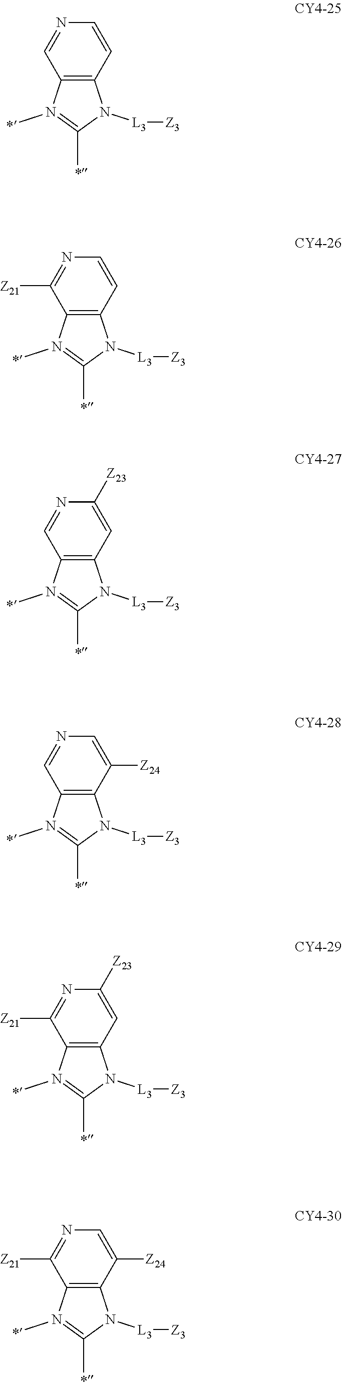

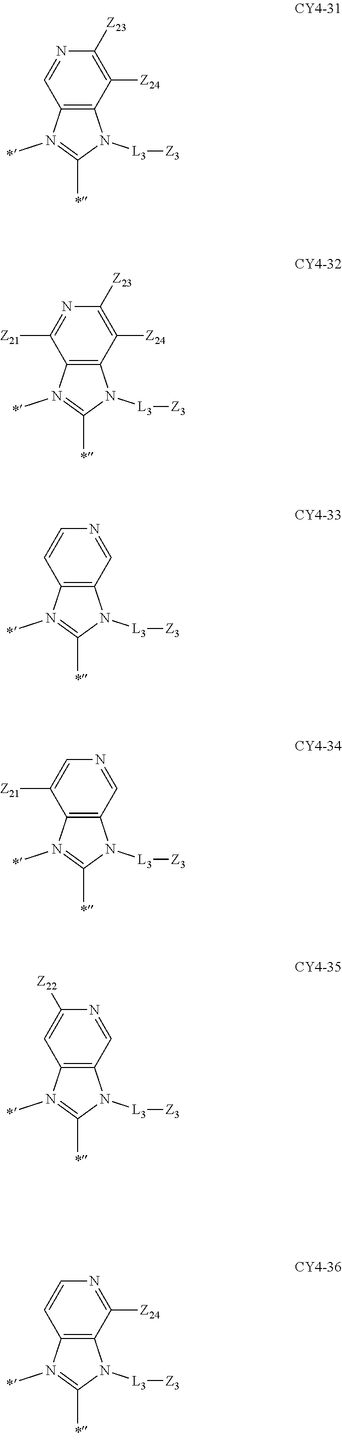

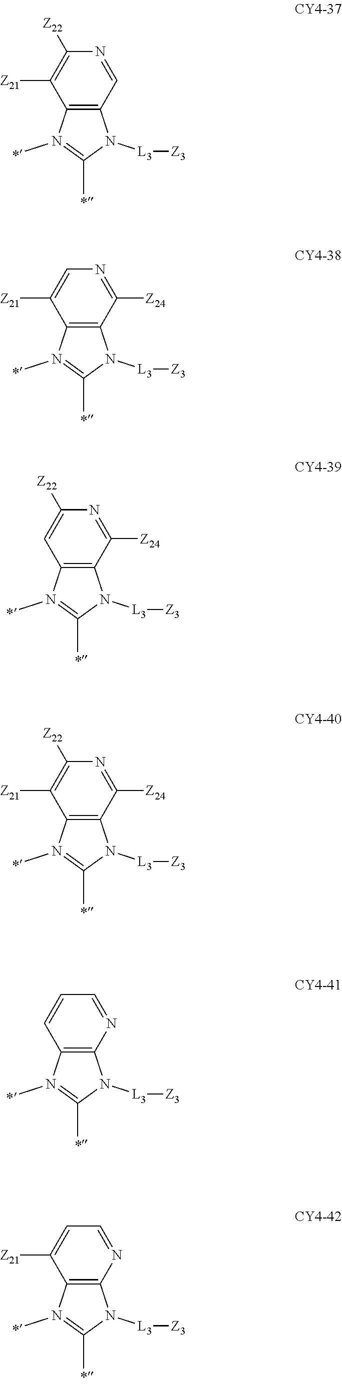

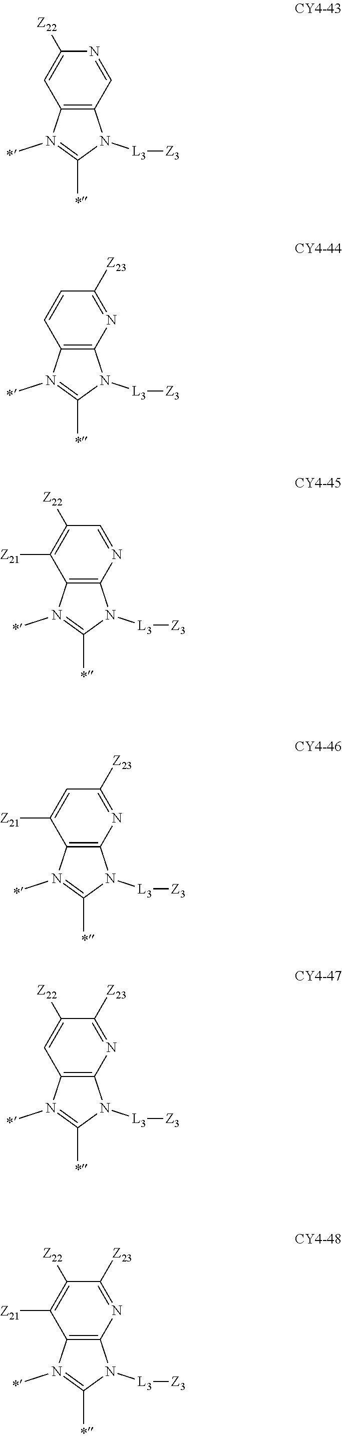

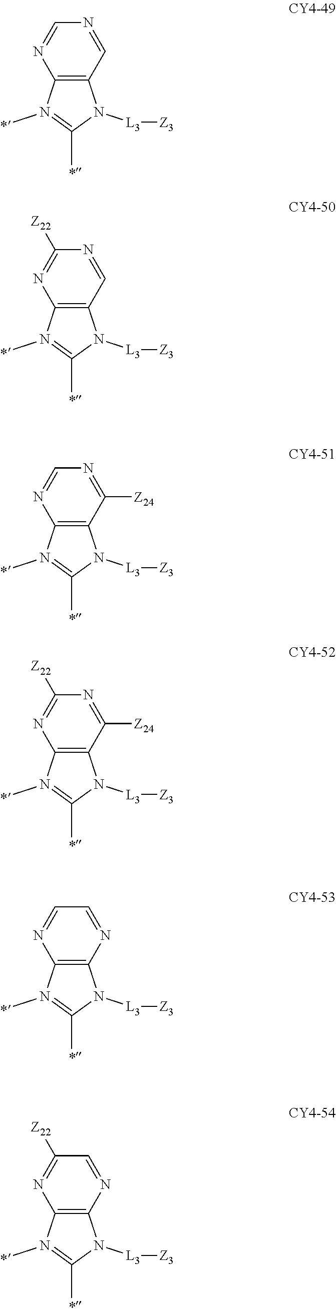

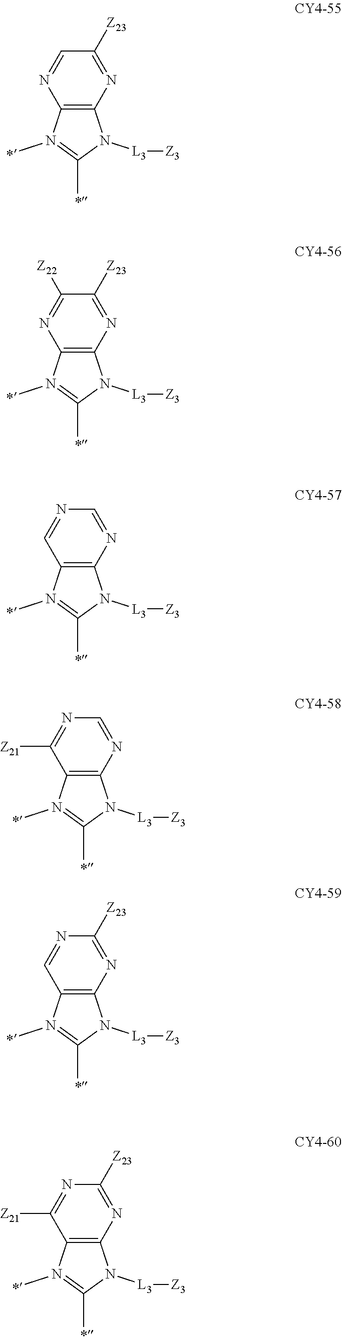

In Formulae CY4-1 to CY4-60,
L₃ and Z₃ may each be understood by referring to the corresponding descriptions thereof provided herein,
Z₂₁ to Z₂₄ may each be understood by referring to the description provided in connection with Z₂, wherein each of Z₂₁ to Z₂₄ may not be hydrogen,
*′ indicates a binding site to M in Formula 1, and
*″ indicates a binding site to a neighboring atom in Formula 3.

In one or more embodiments, two or more of a plurality of Z₂ groups in a group represented by in Formula 3 may be linked to form a C₅-C₃₀ carbocyclic group that is unsubstituted or substituted with at least one R₁₀ₐ, or two or more of the plurality of Z₂ groups in the group represented by:

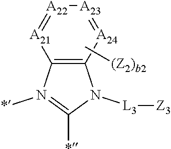

in Formula 3 may be linked to form a C₁-C₃₀ heterocyclic group that is unsubstituted or substituted with at least one R₁₀ₐ. As a result, a group represented by:

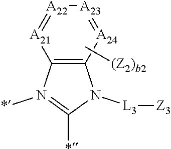

in Formula 3 may be a group represented by one of Formulae CY4(1) to CY4(4):

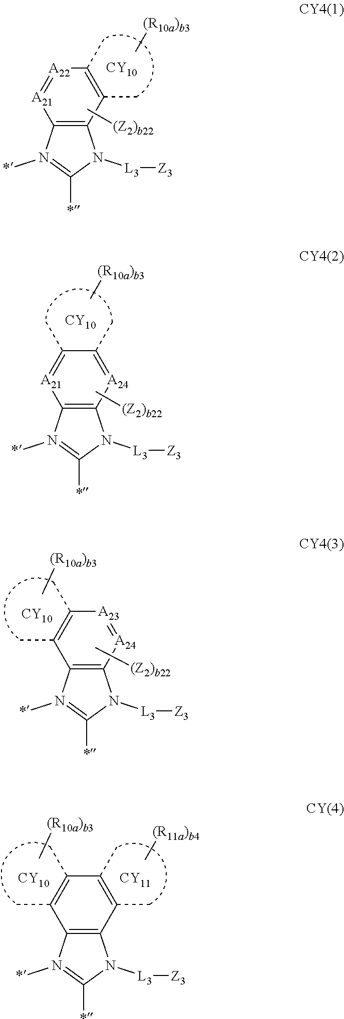

In Formulae CY4(1) to CY4(4),
A₂₁ to A₂₄, L₃, Z₂, Z₃ and R₁₀ₐ are the same as described above,
b22 may be an integer from 0 to 2,
ring CY₁₀ and ring CY₁₁ may each independently be a C₅-C₃₀ carbocyclic group or a C₁-C₃₀ heterocyclic group,
R₁₁ₐ is the same as described in connection with R₁₀ₐ,
   b3 and b4 may each independently be an integer from 0 to 20, when b3 is 2 or more, two or more R₁₀ₐ groups may be identical to or different from each other, and when b4 is 2 or more, two or more R₁₁ₐ groups may be identical to or different from each other,
*′ indicates a binding site to M in Formula 1, and
*″ indicates a binding site to a neighboring atom in Formula 3.

For example, ring CY₁₀ and ring CY₁₁ in Formulae CY4(1) to CY4(4) may each independently be a benzene group or a naphthalene group.

In one or more embodiments, a group represented by:

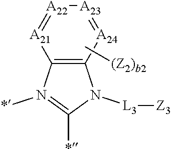

in Formula 3 may be a group represented by one of Formulae CY4(1)-1 to CY4(1)-4, CY4(2)-1 to CY4(2)-4, CY4(3)-1 to CY4(3)-4 and CY4(4)-1:

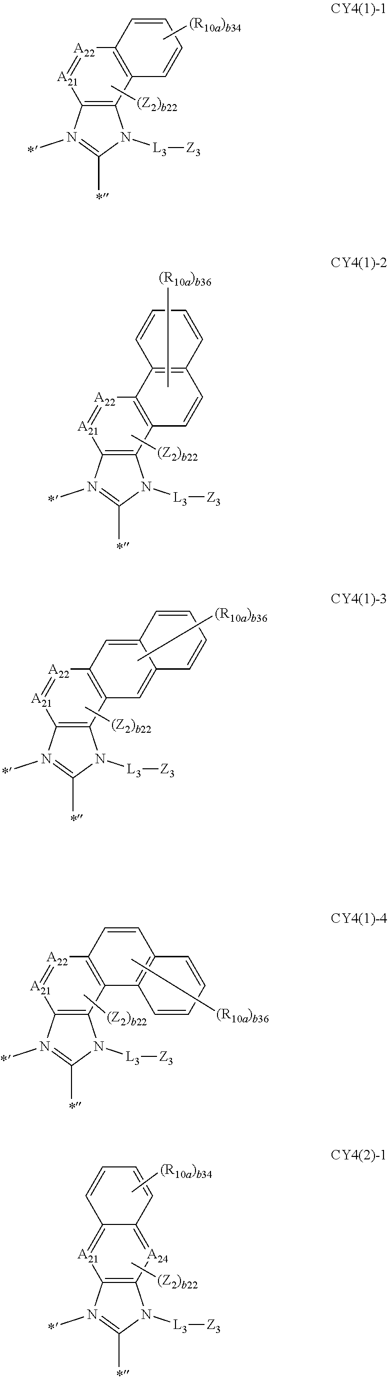

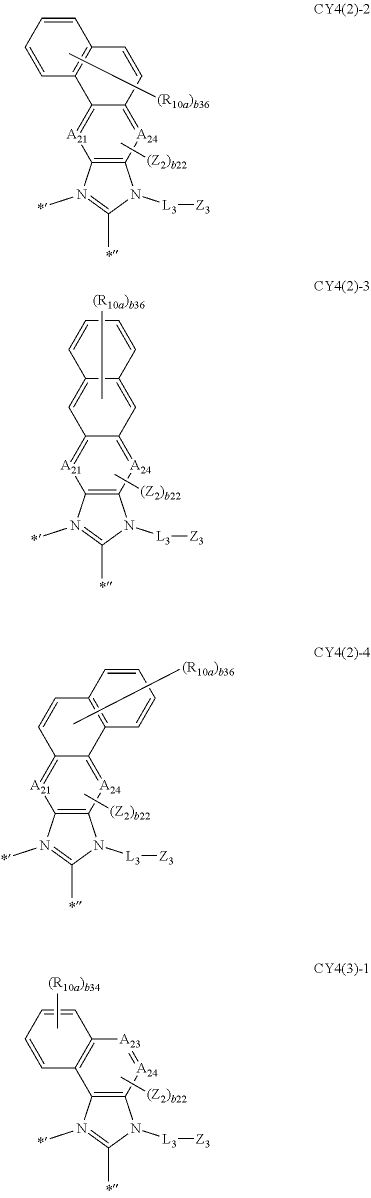

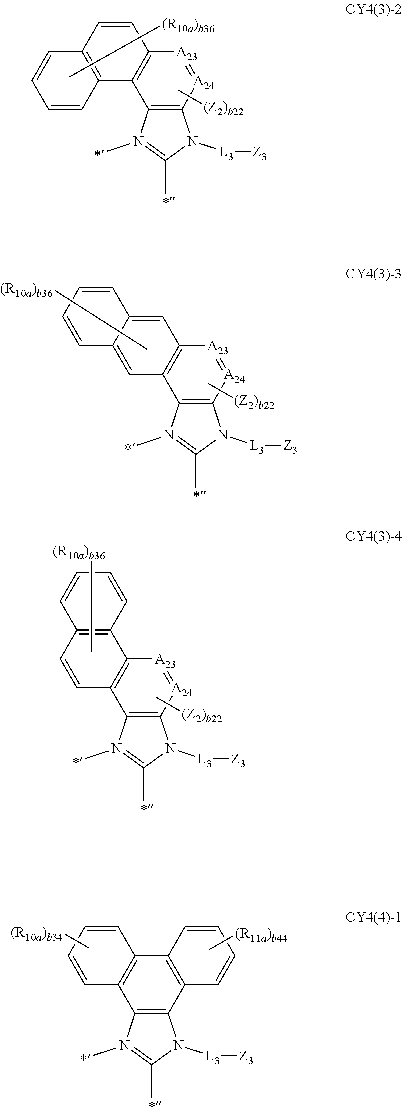

In Formulae CY4(1)-1 to CY4(1)-4, CY4(2)-1 to CY4(2)-4, CY4(3)-1 to CY4(3)-4 and CY4(4)-1,
A₂₁ to A₂₄, L₃, Z₂, Z₃ and R₁₀ₐ are the same as described above,
b22 may be an integer from 0 to 2,
R₁₁ₐ is the same as described in connection with R₁₀ₐ,
b34 and b44 may each independently be an integer from 0 to 4, when b34 is 2 or more, two or more R₁₀ₐ groups may be identical to or different from each other, and when b44 is 2 or more, two or more R₁₁ₐ groups may be identical to or different from each other,
b36 may be an integer from 0 to 6, when b36 is 2 or more, two or more R₁₀ₐ groups may be identical to or different from each other,
*′ indicates a binding site to M in Formula 1, and
*″ indicates a binding site to a neighboring atom in Formula 3.

In one or more embodiments, the organometallic compound represented by Formula 1 may emit red light or green light, for example, red light or green light, each having a maximum emission wavelength of 500 nm or more, for example, 500 nm or more and 850 nm or less. For example, the organometallic compound may emit green light.

For example, the organometallic compound may be one of Compounds 1 to 4010:

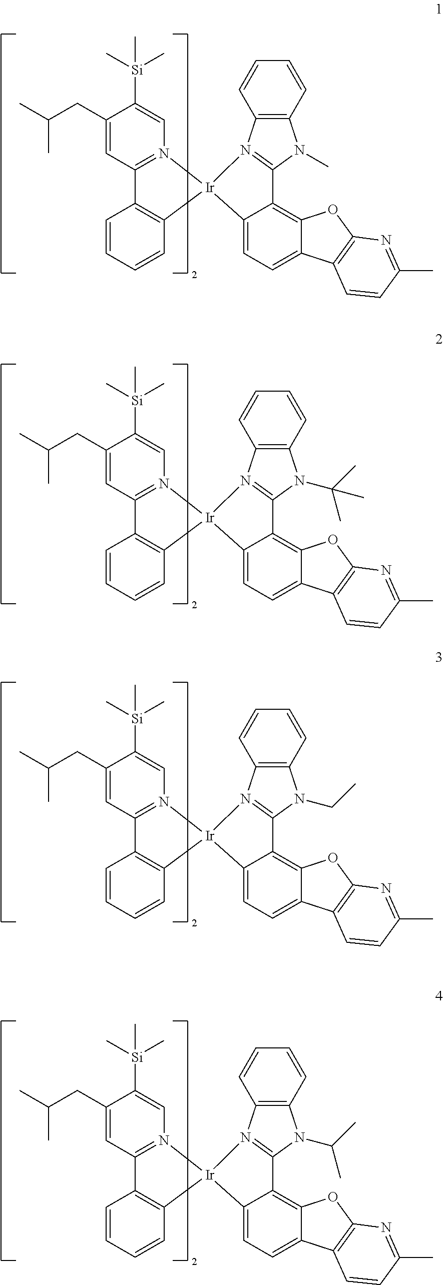

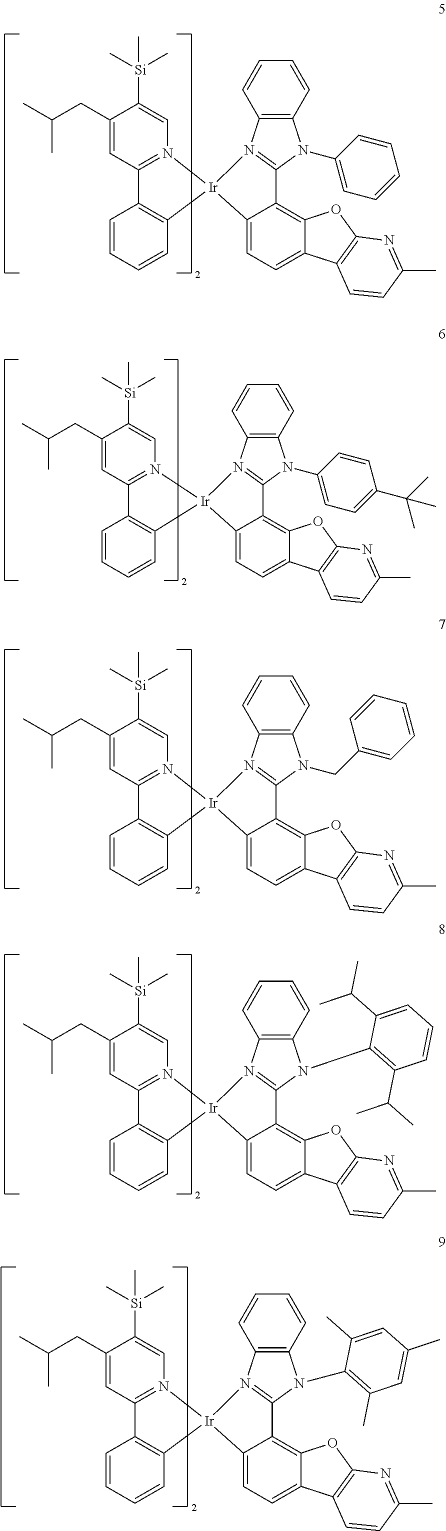

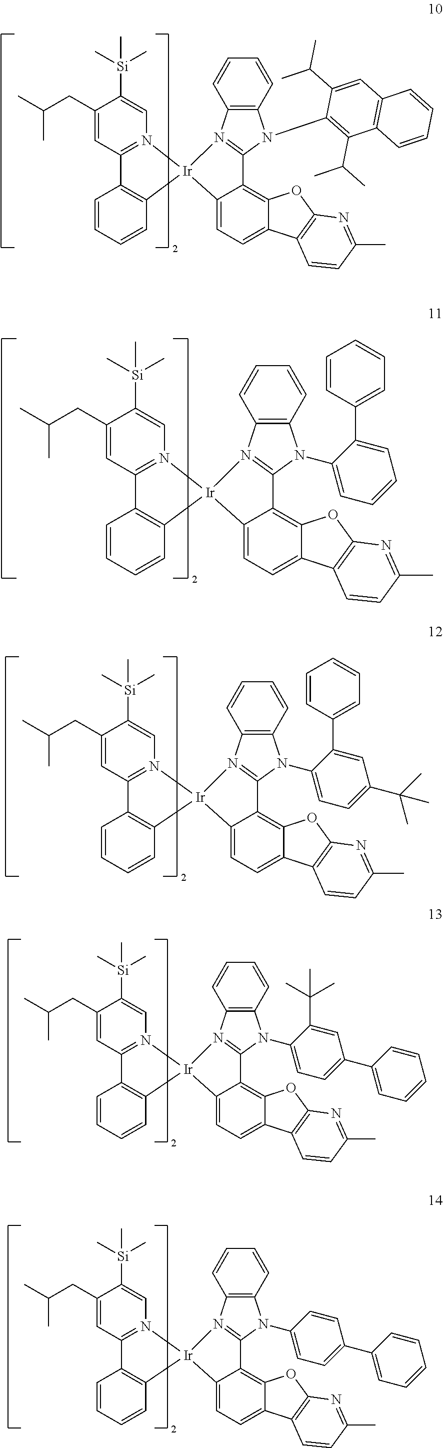

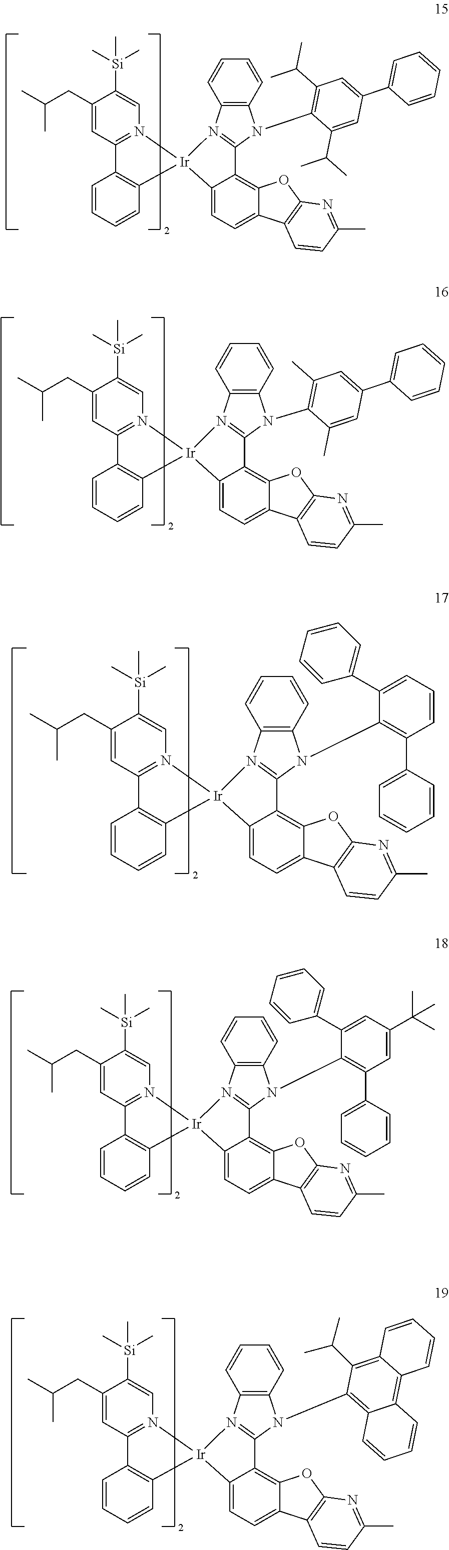

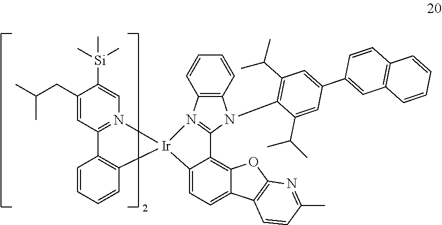

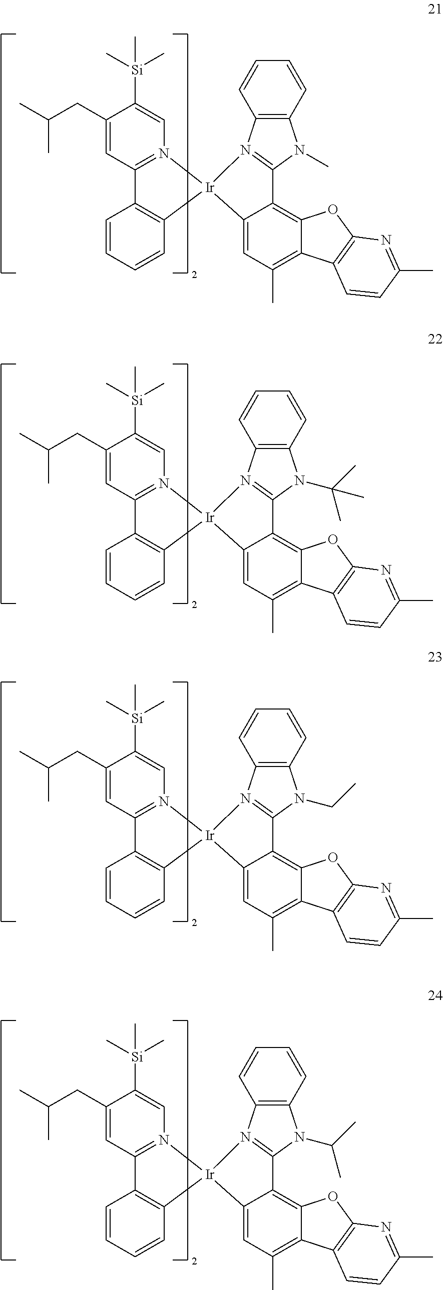

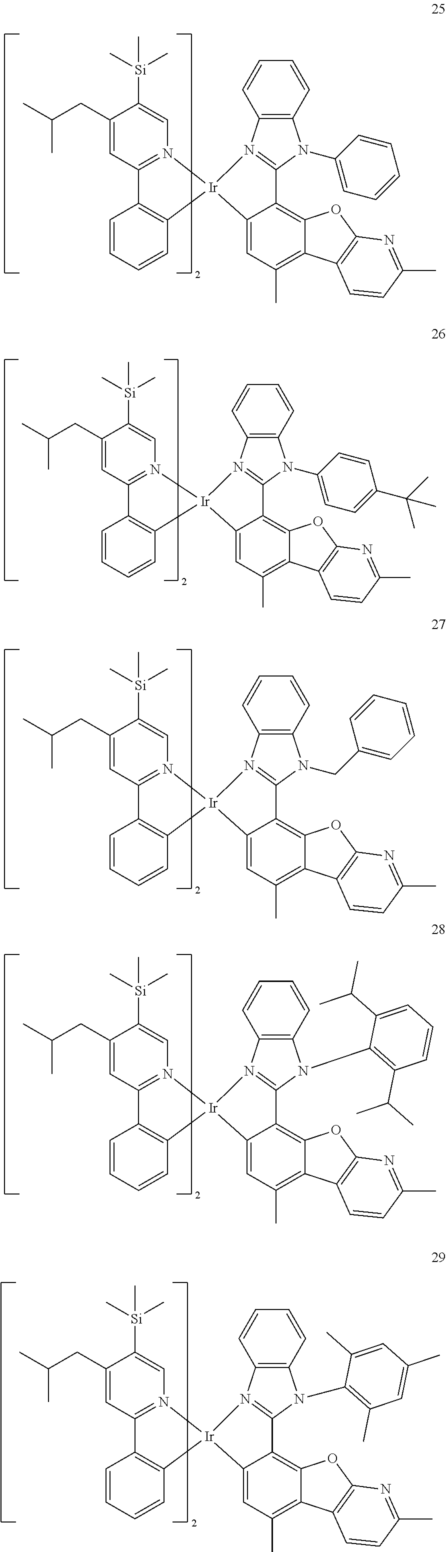

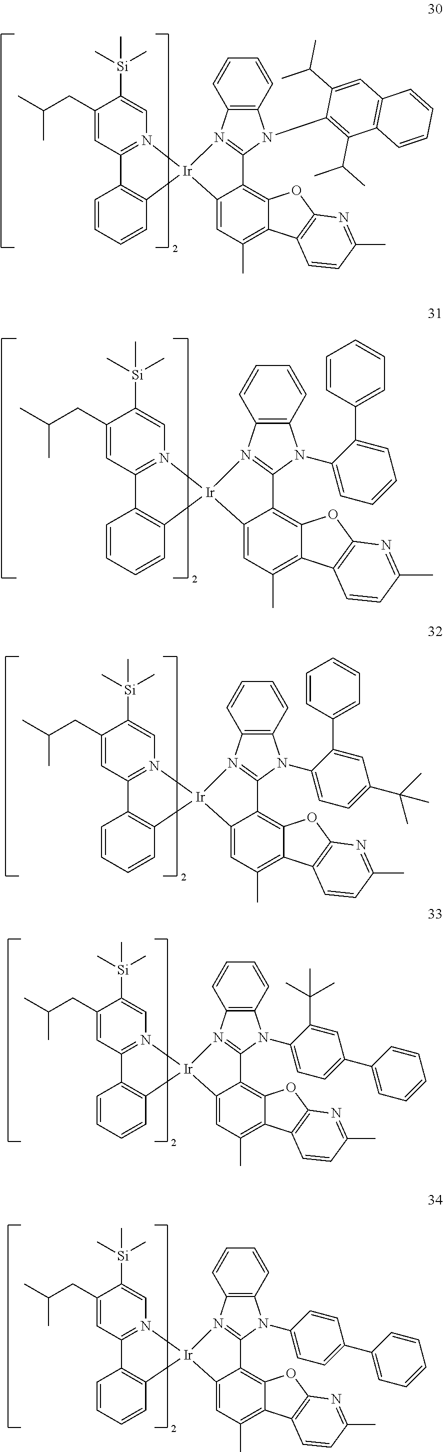

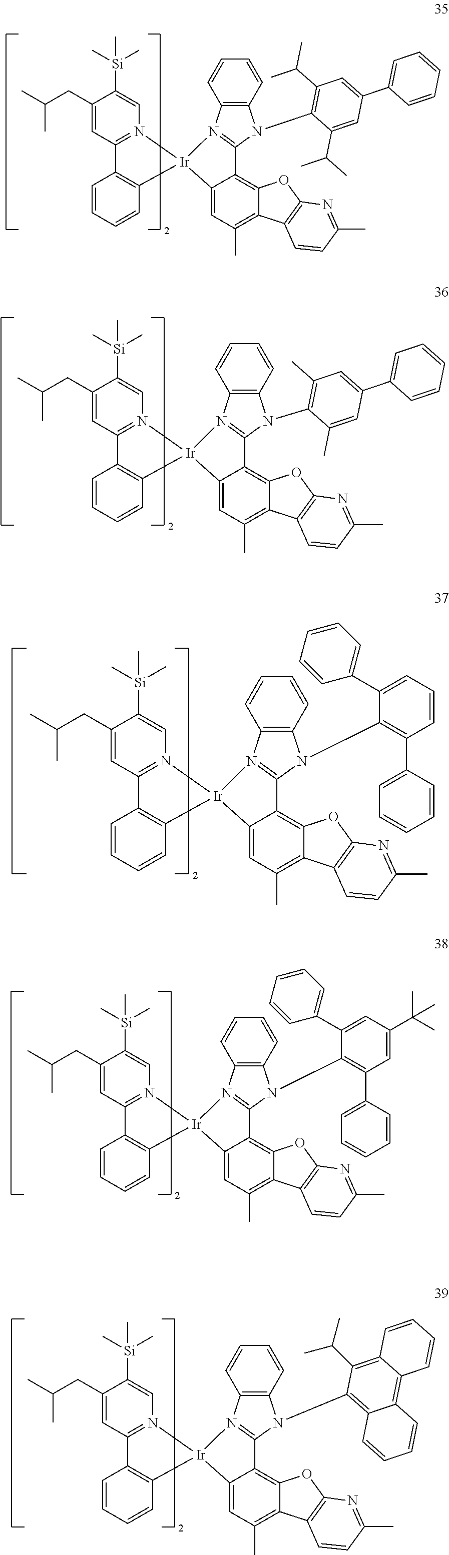

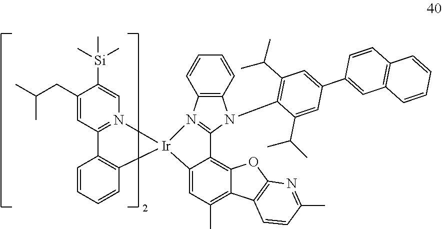

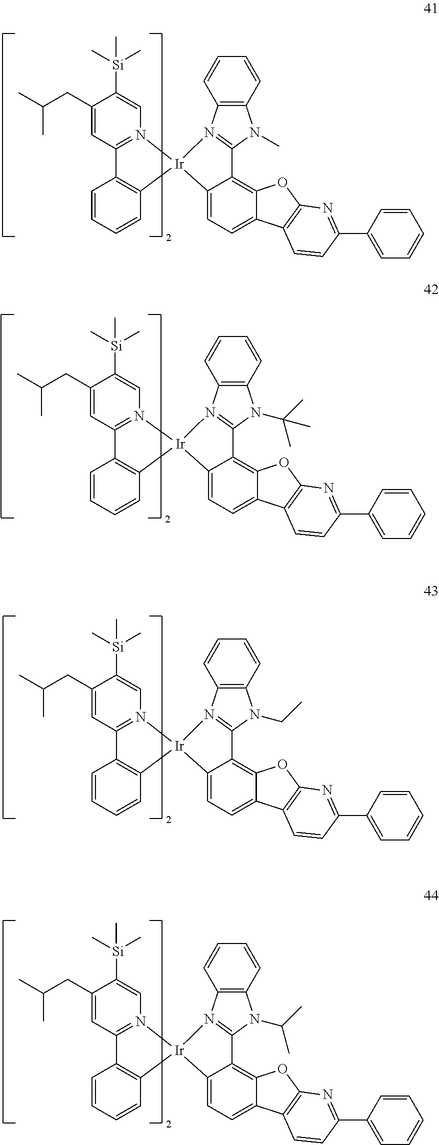

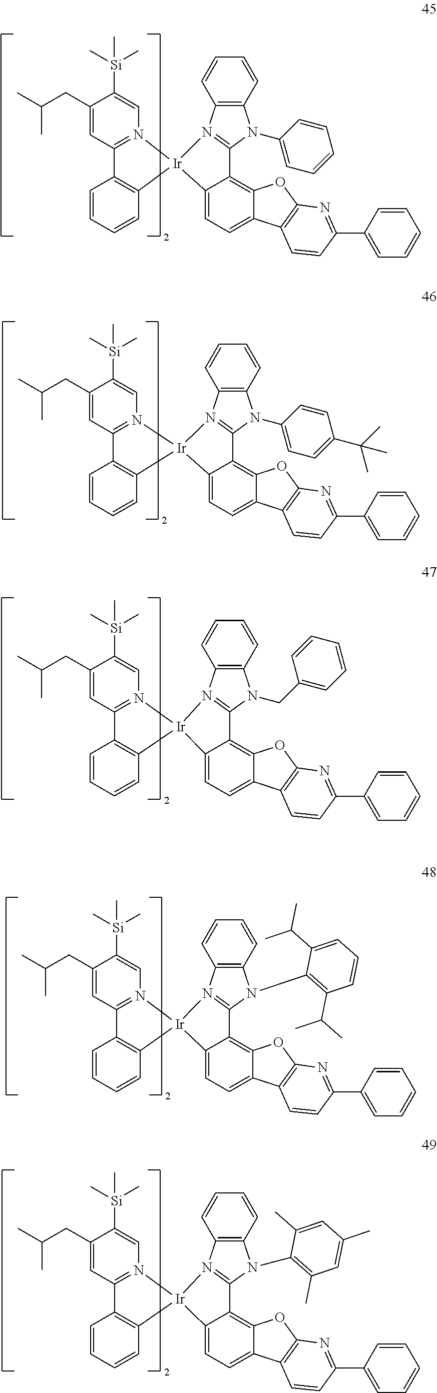

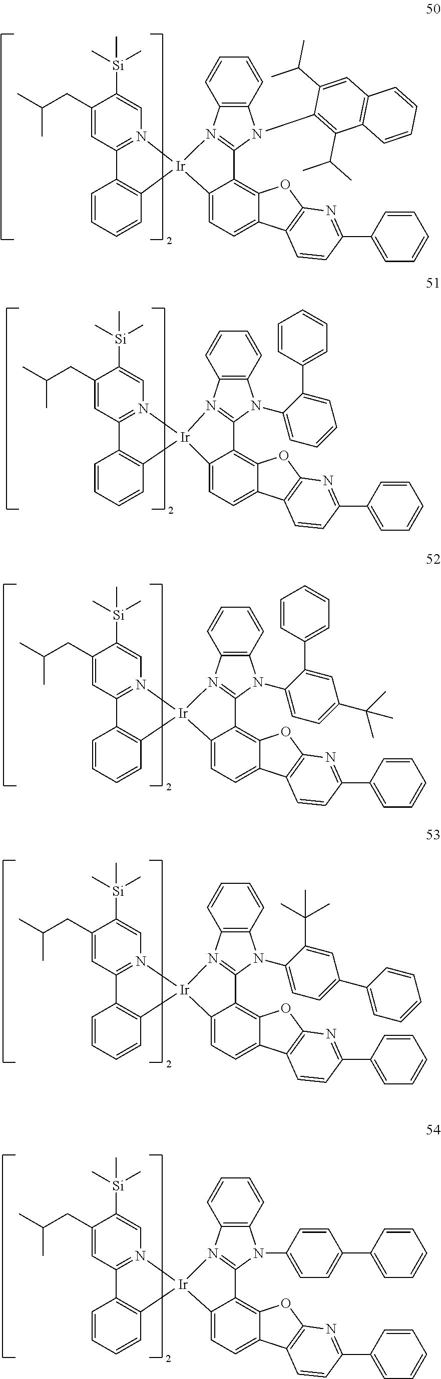

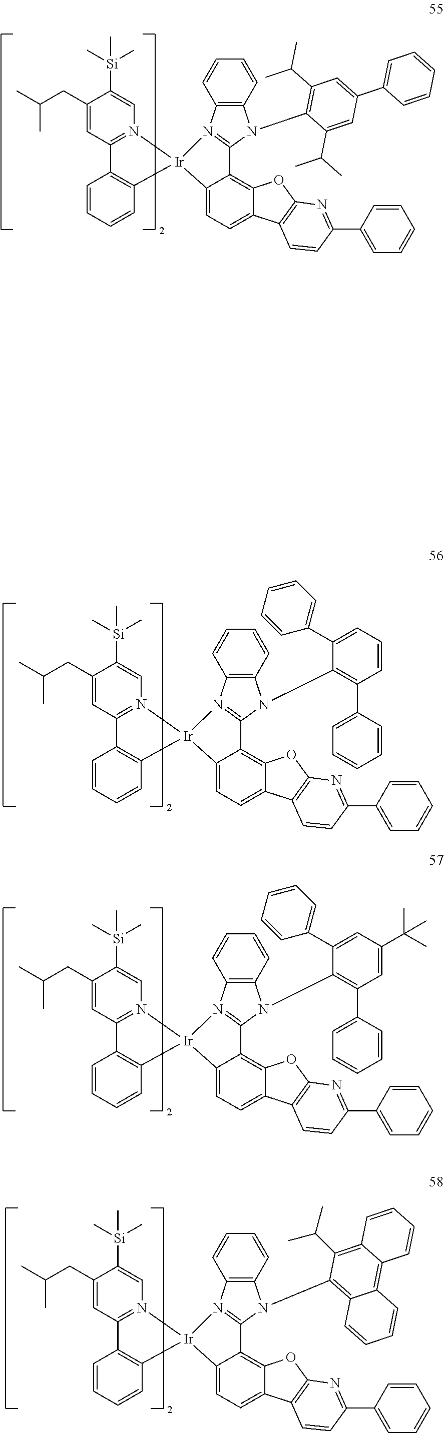

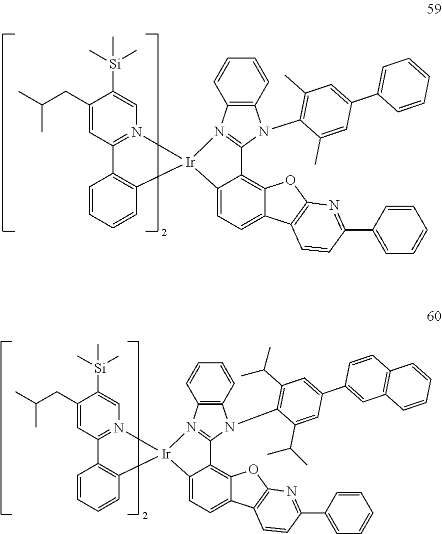

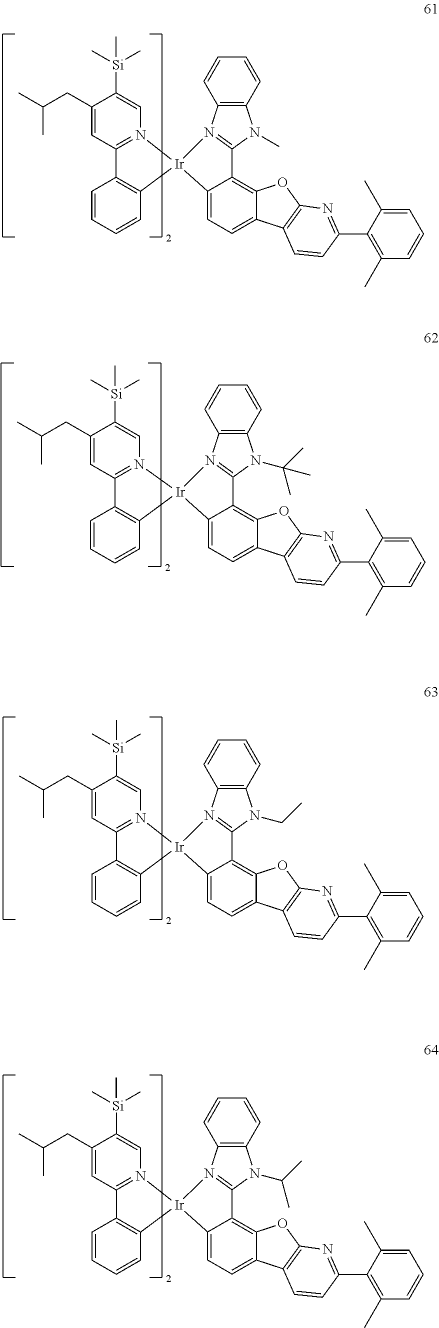

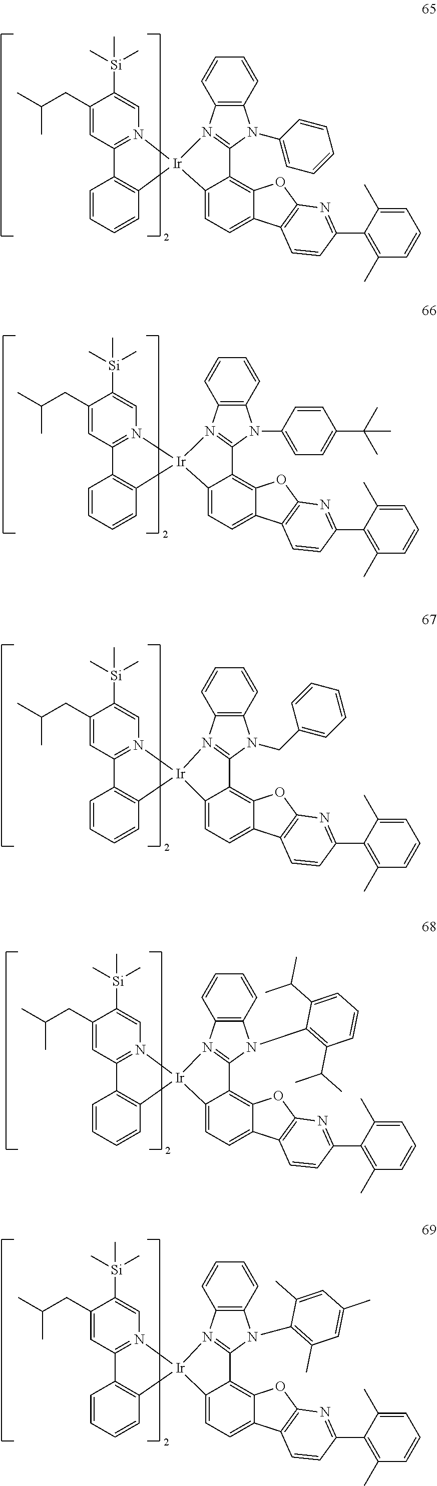

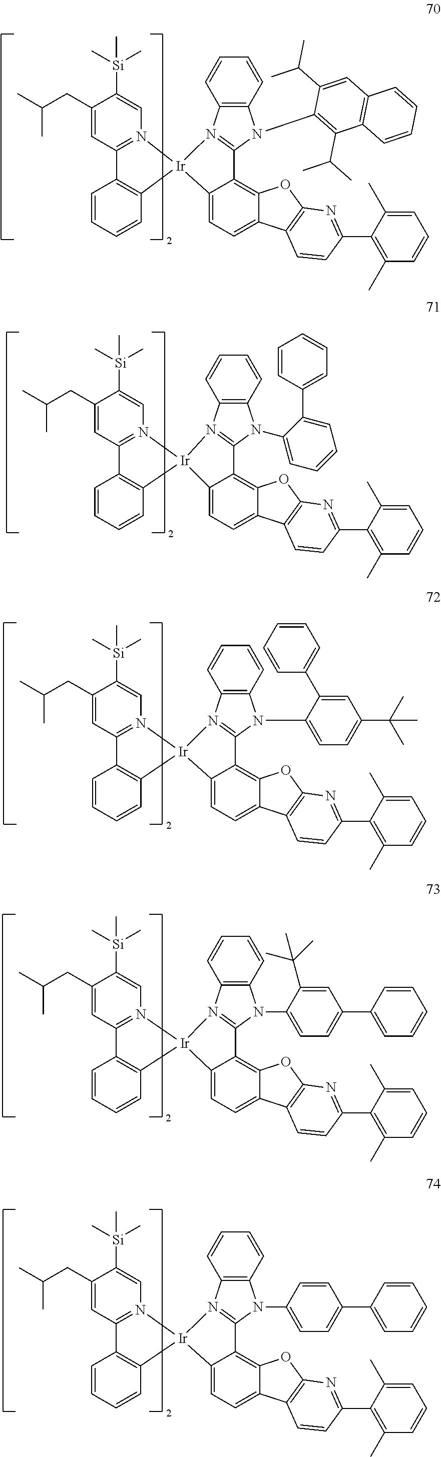

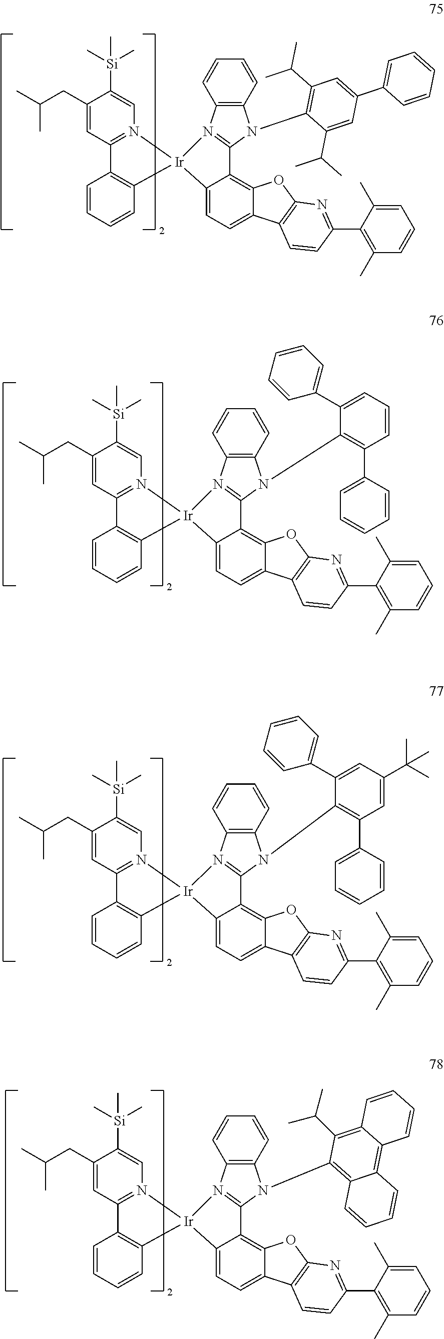

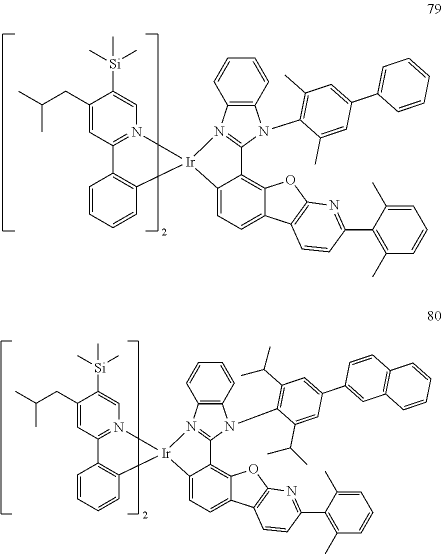

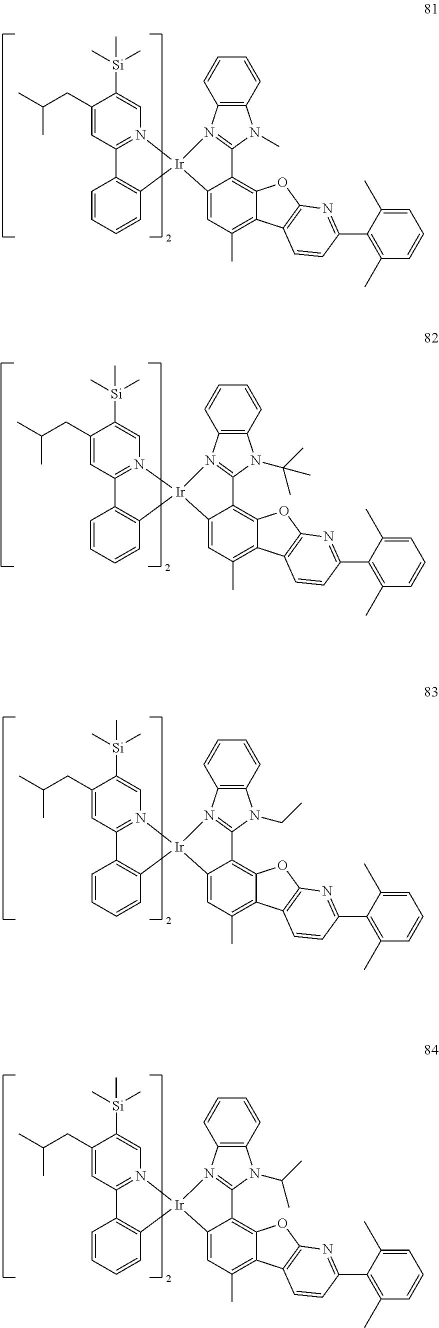

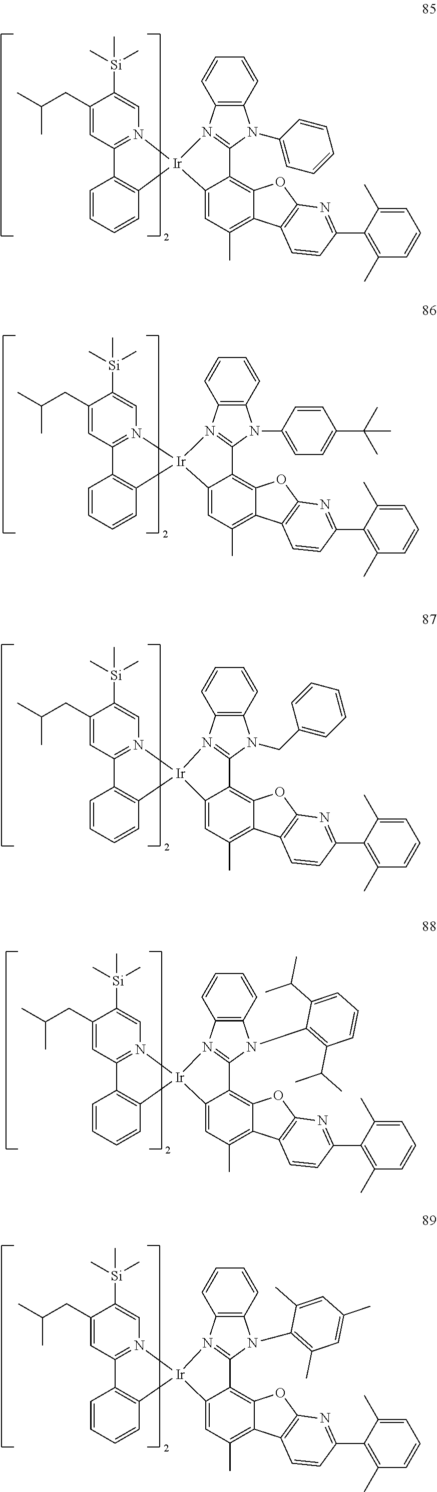

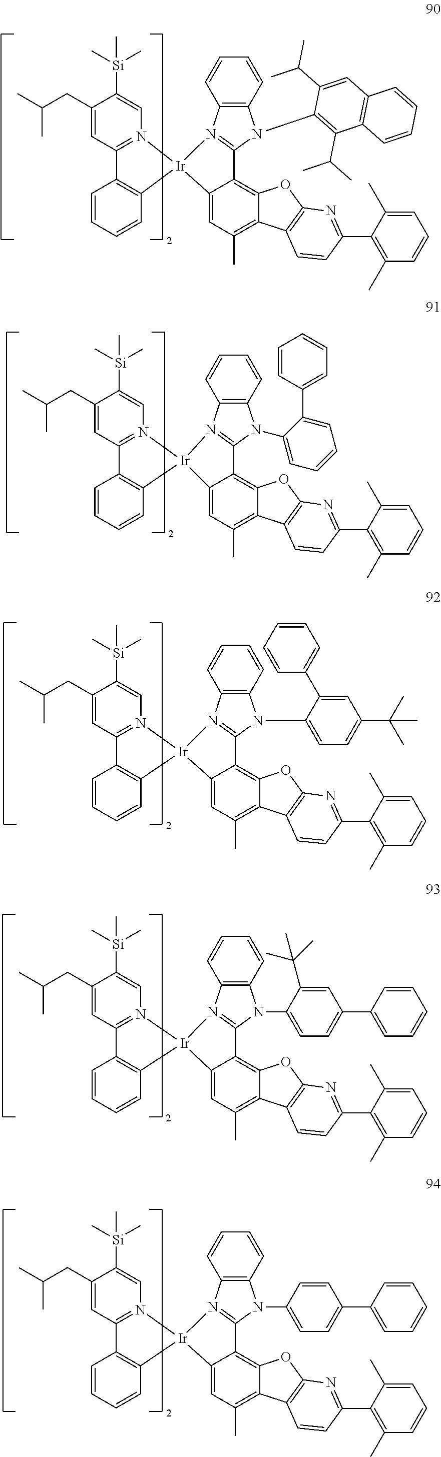

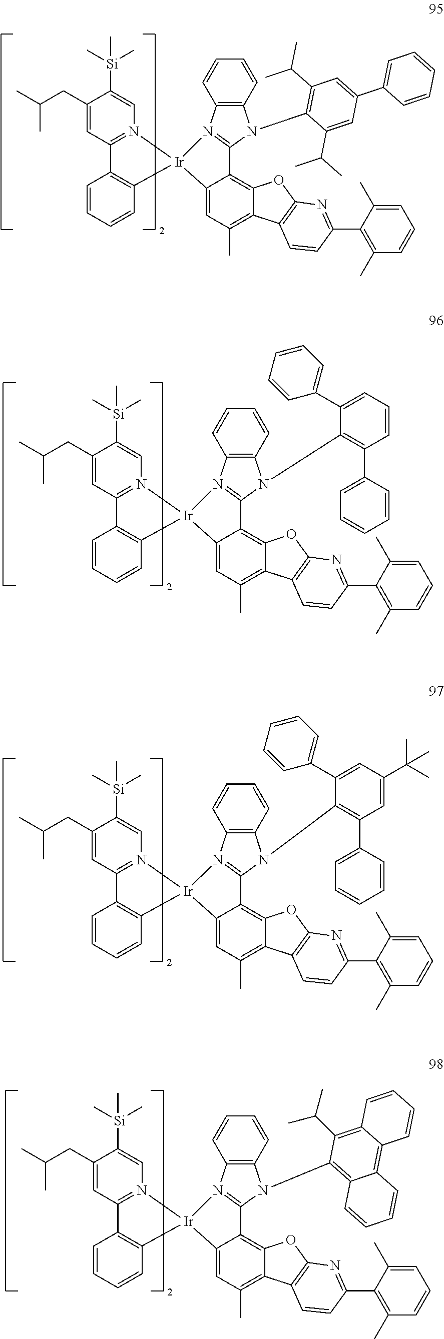

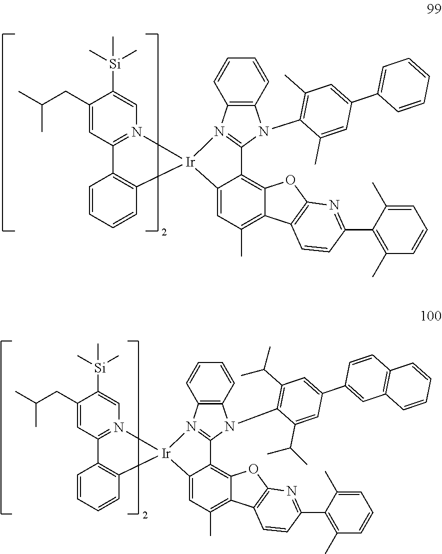

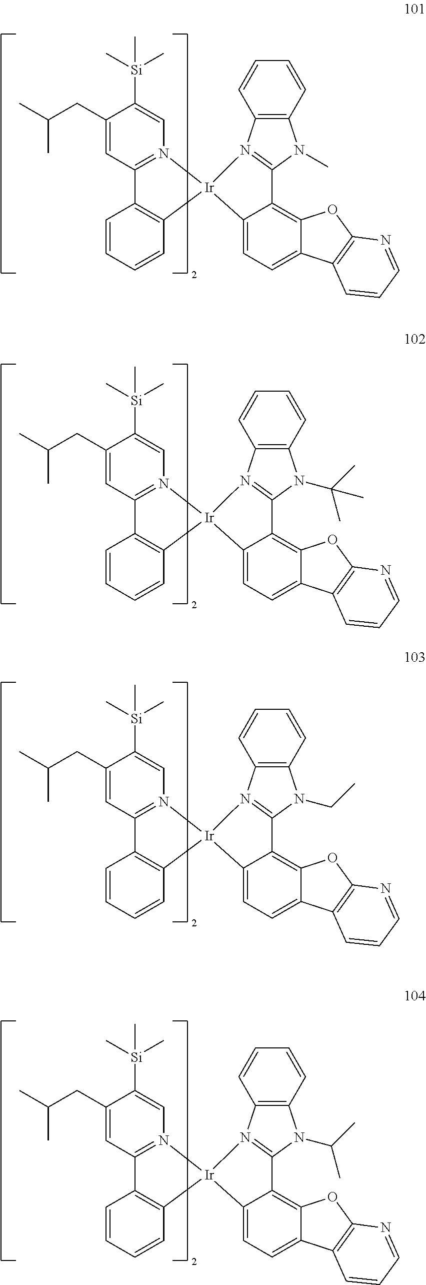

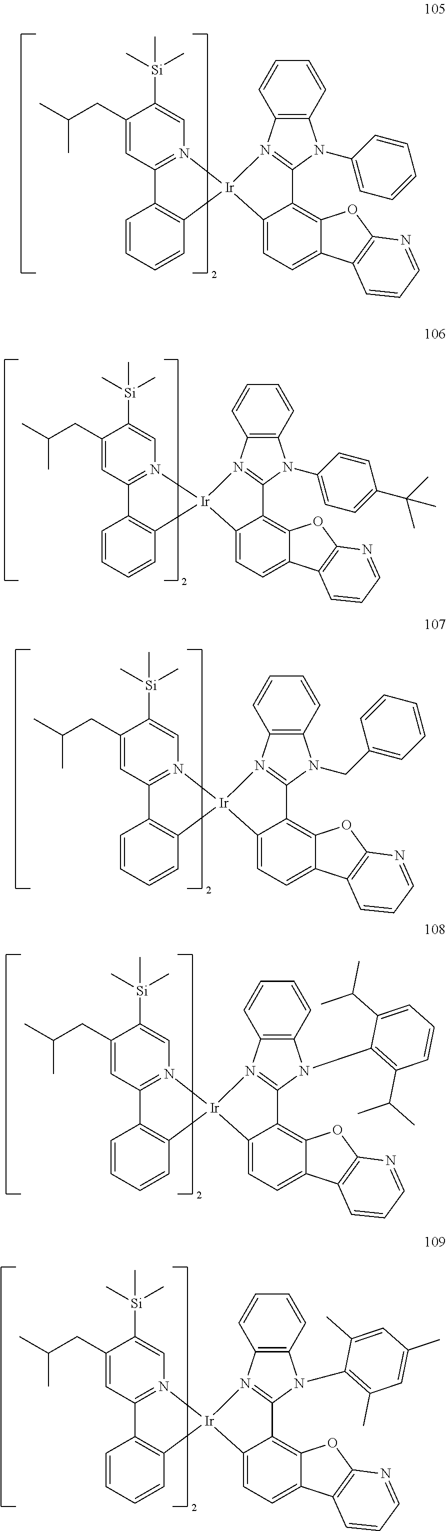

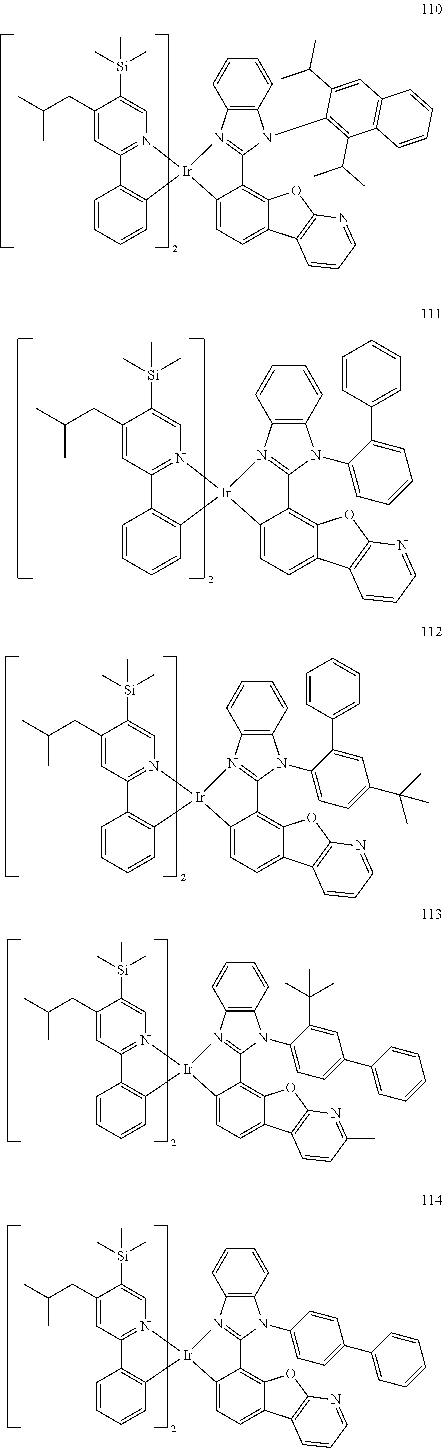

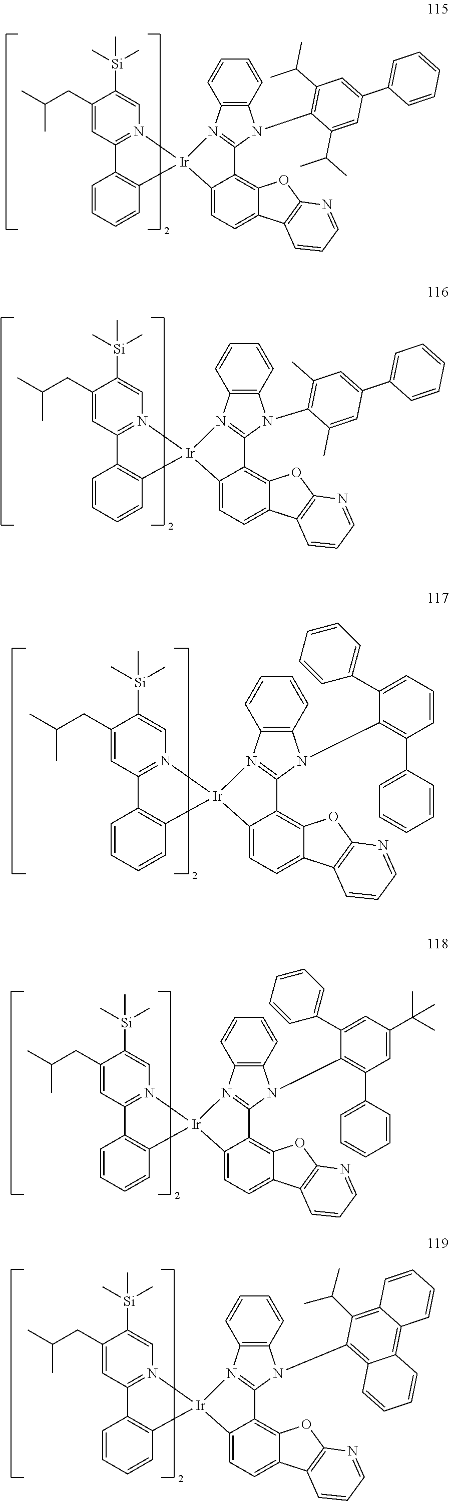

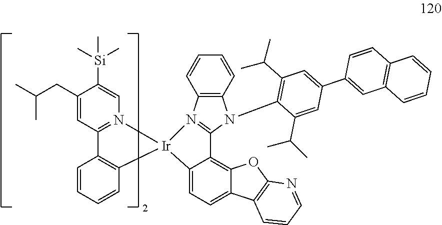

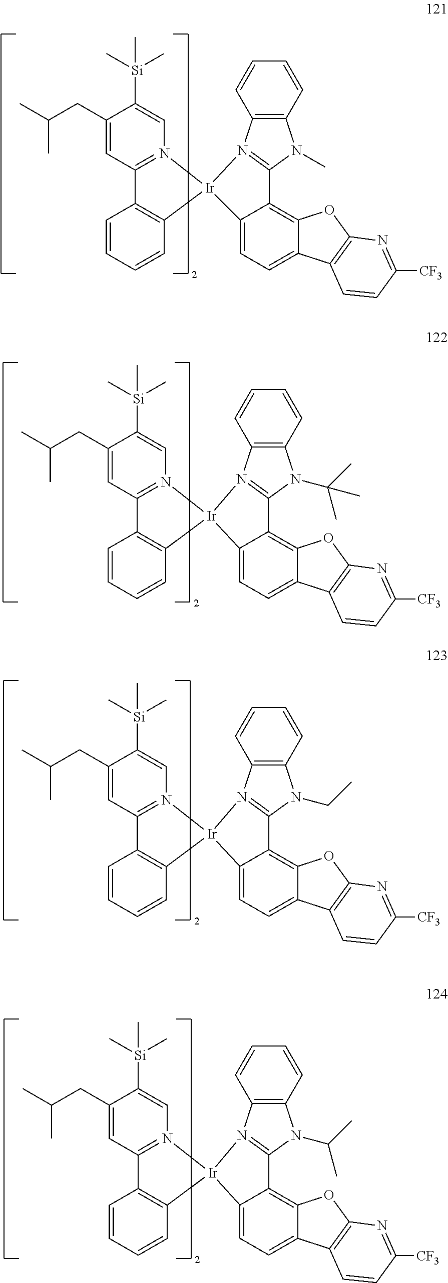

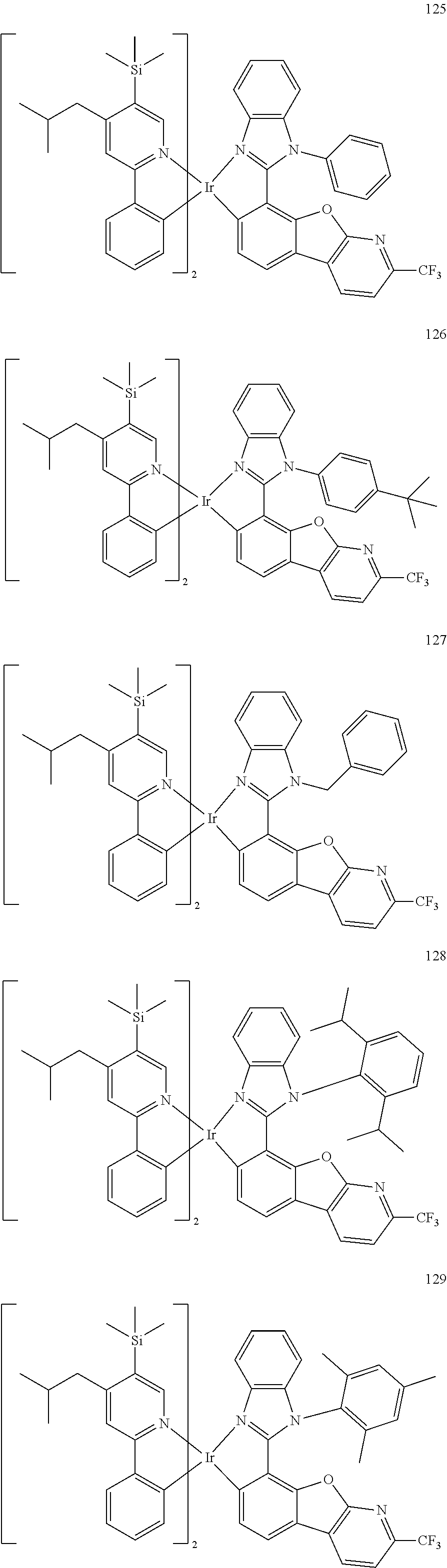

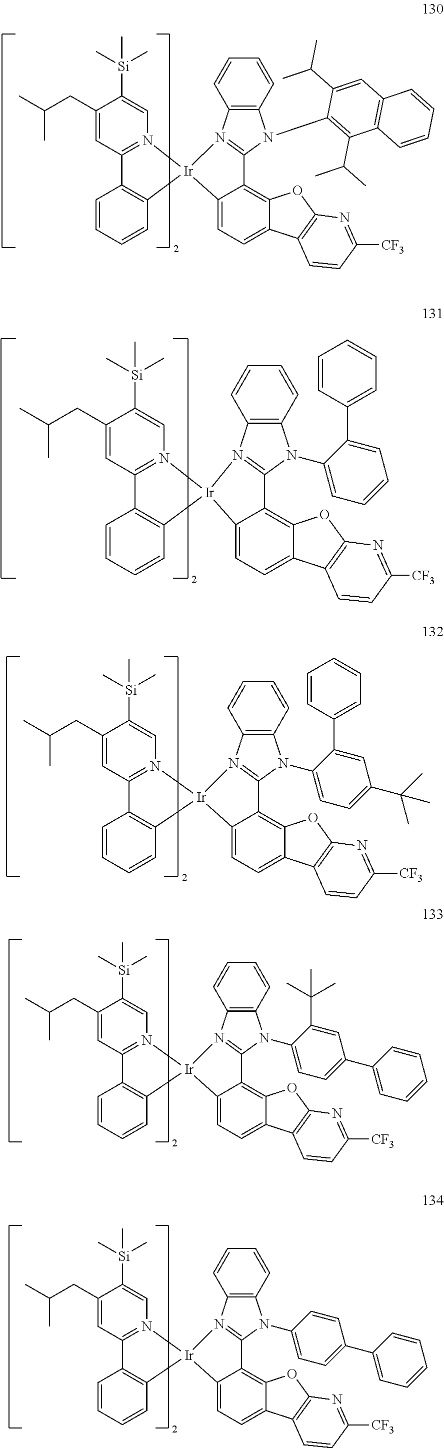

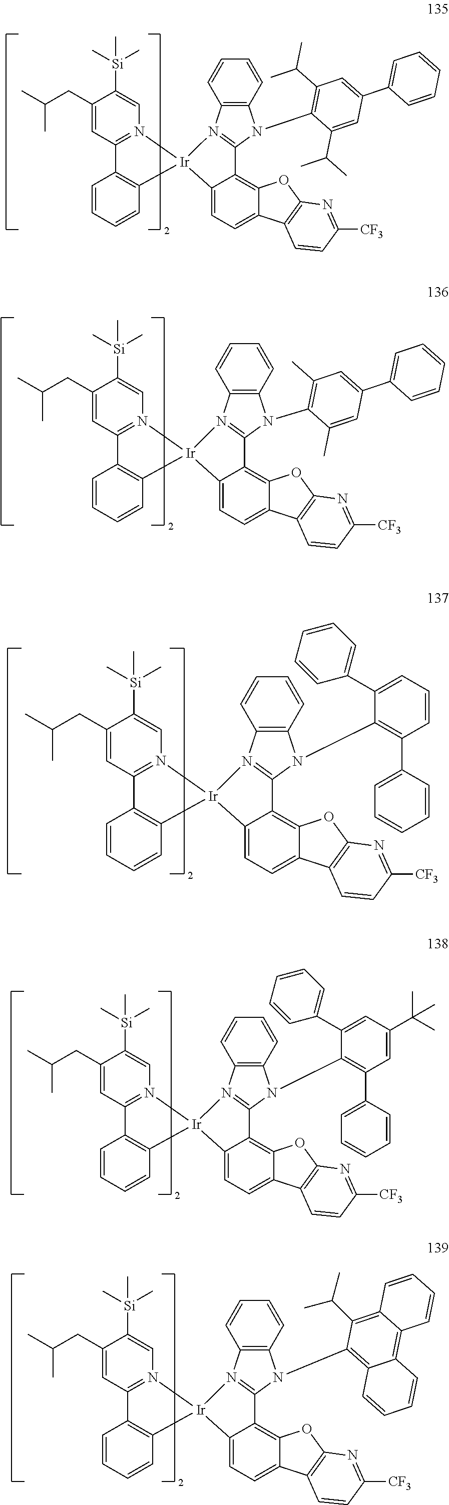

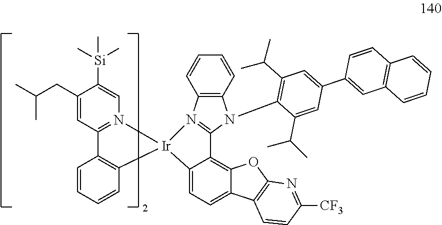

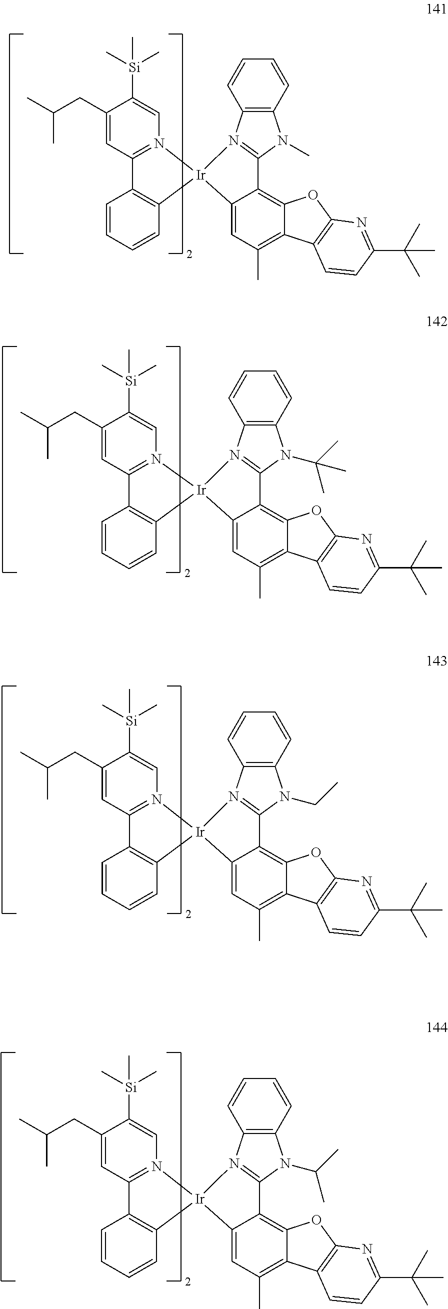

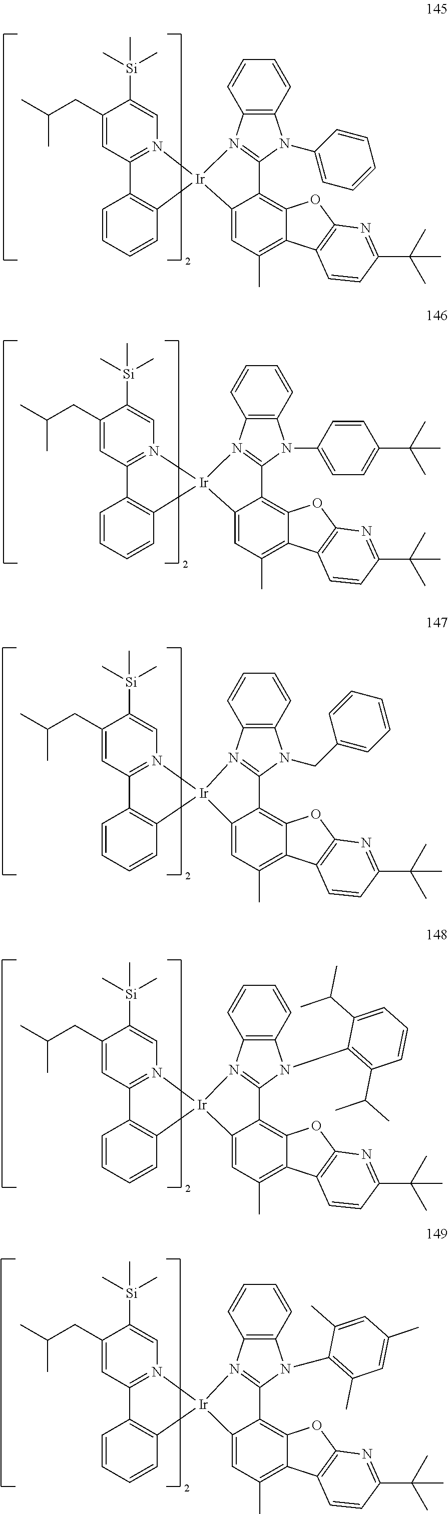

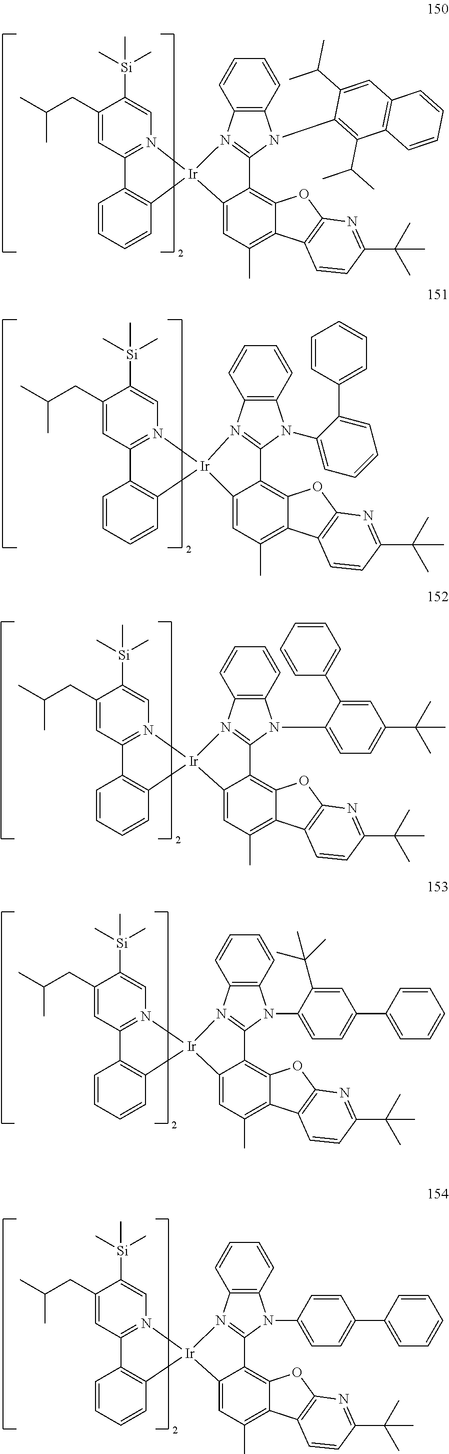

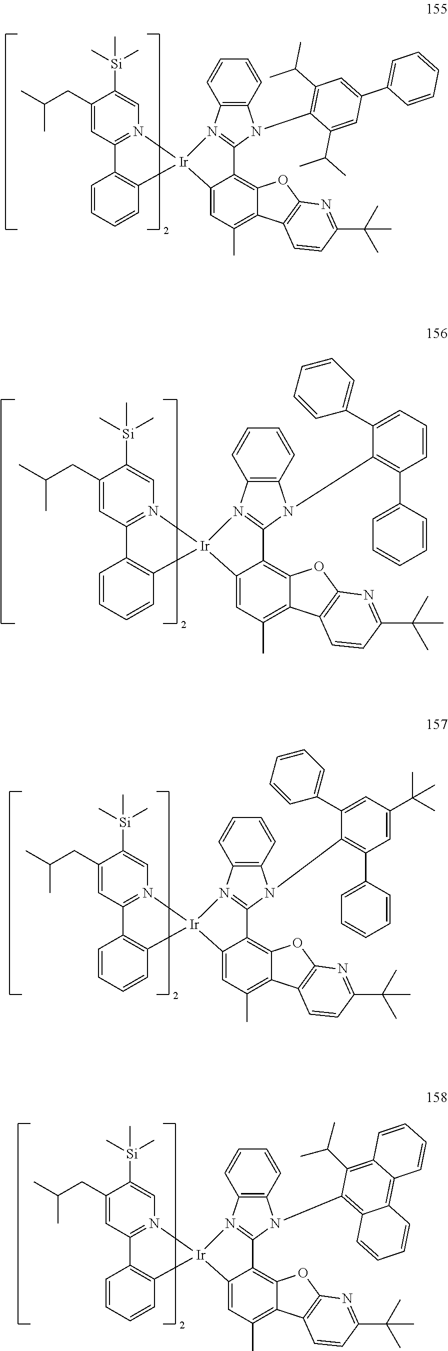

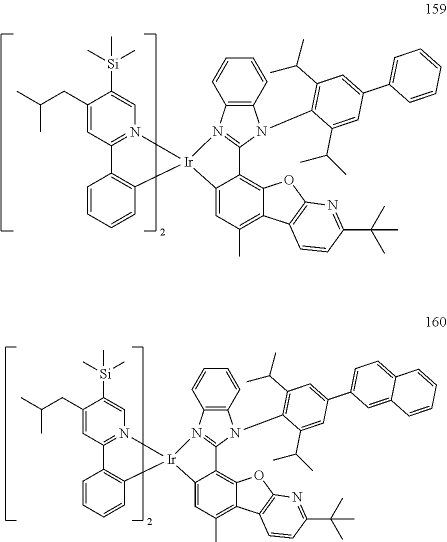

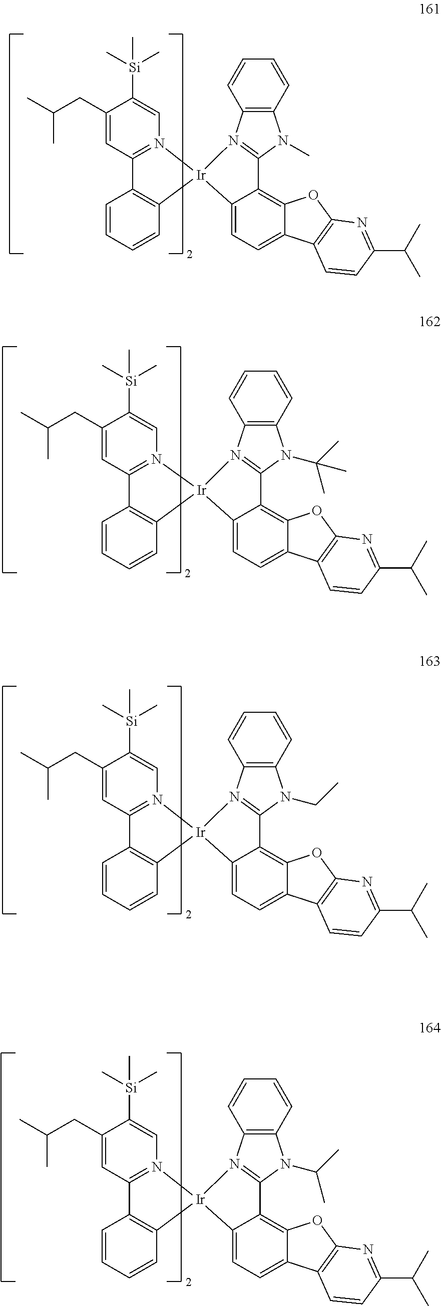

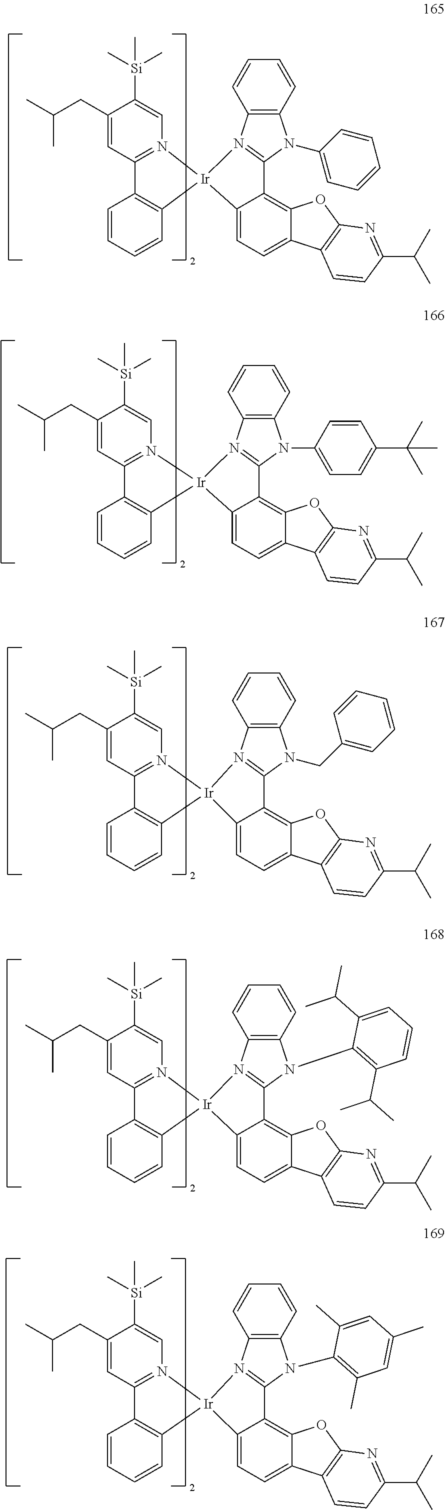

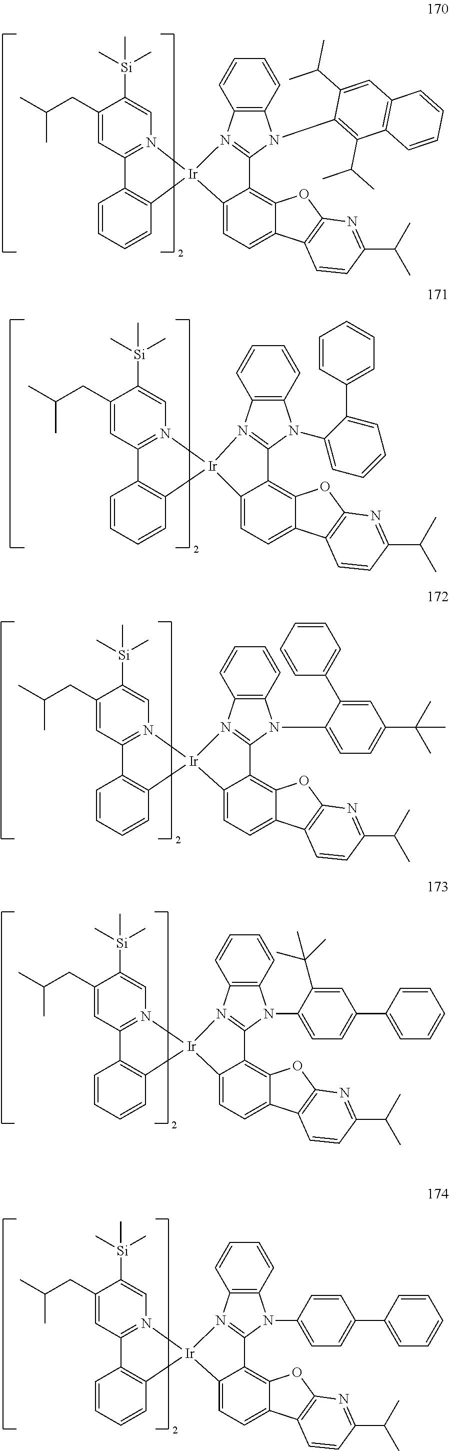

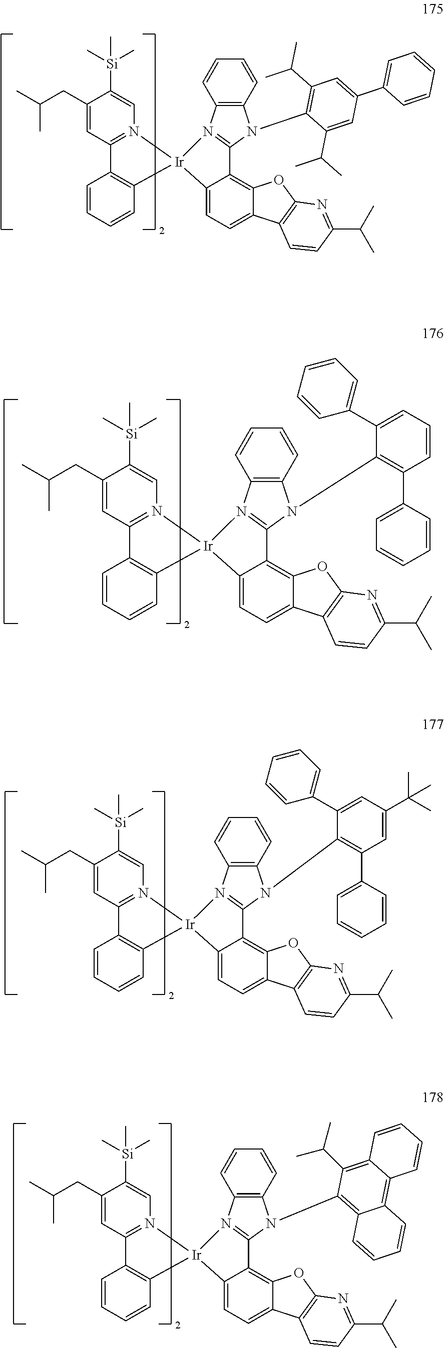

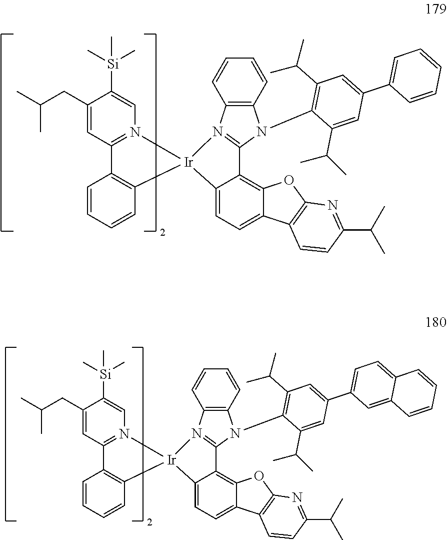

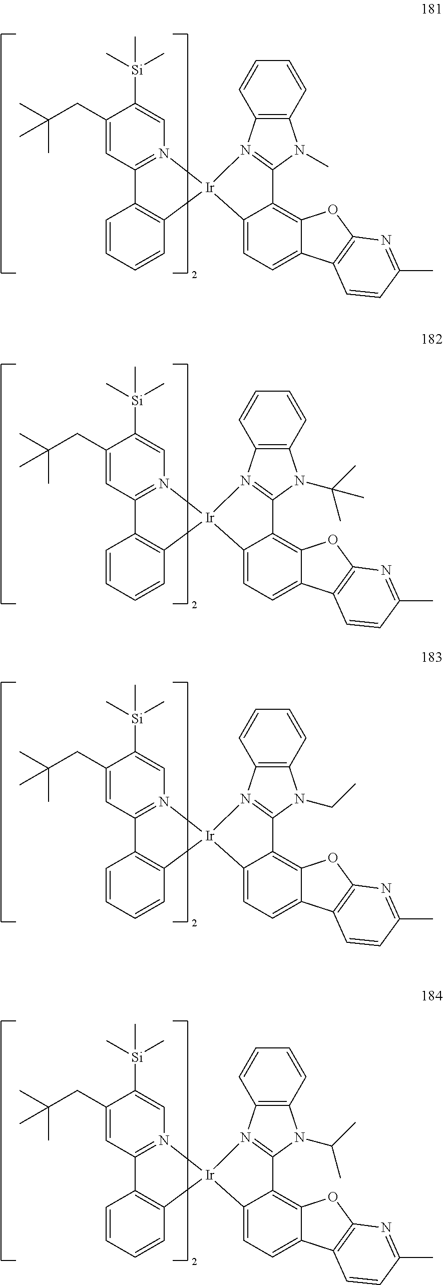

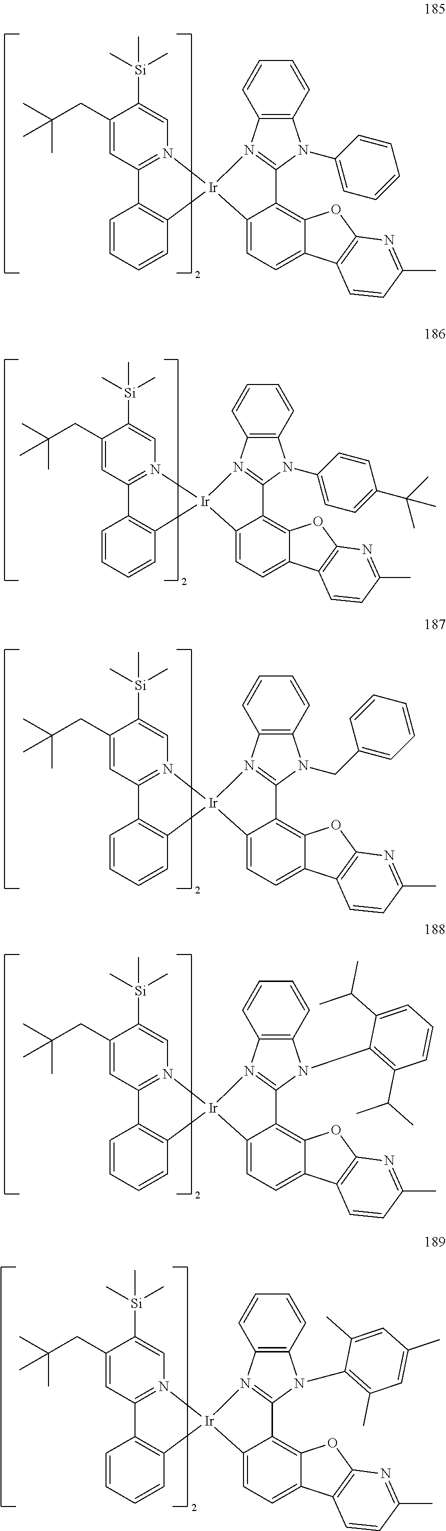

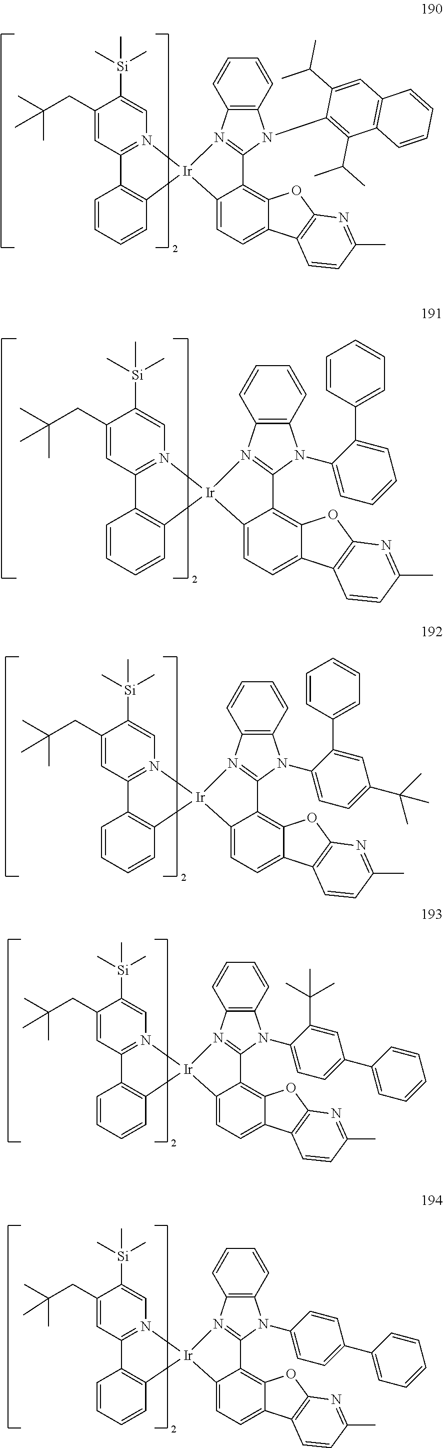

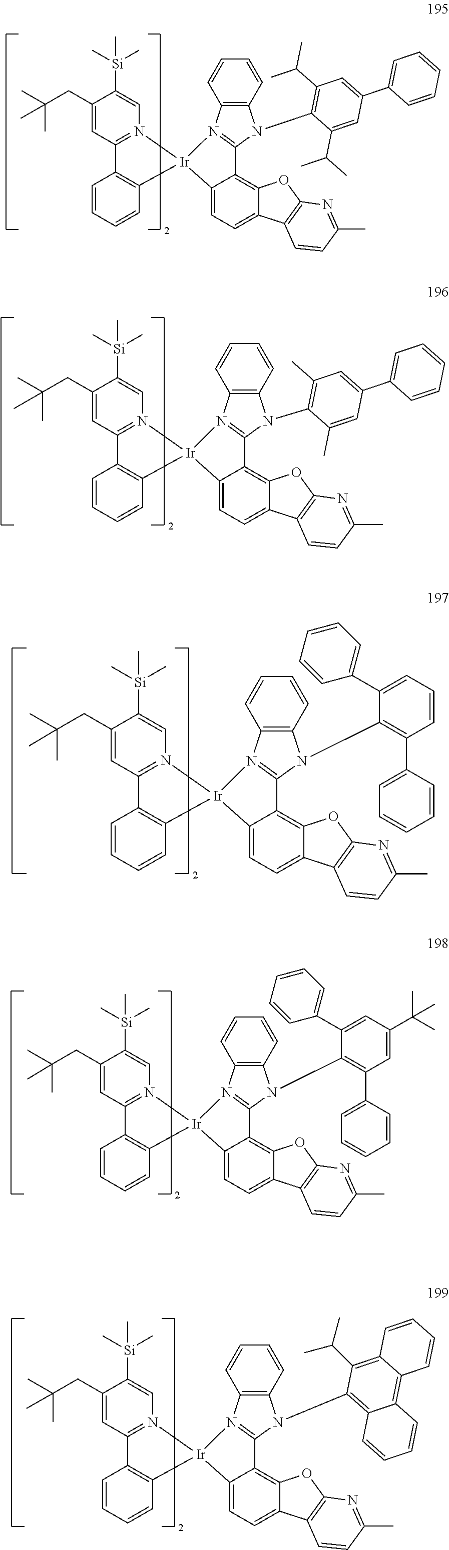

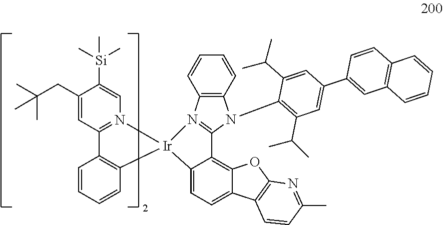

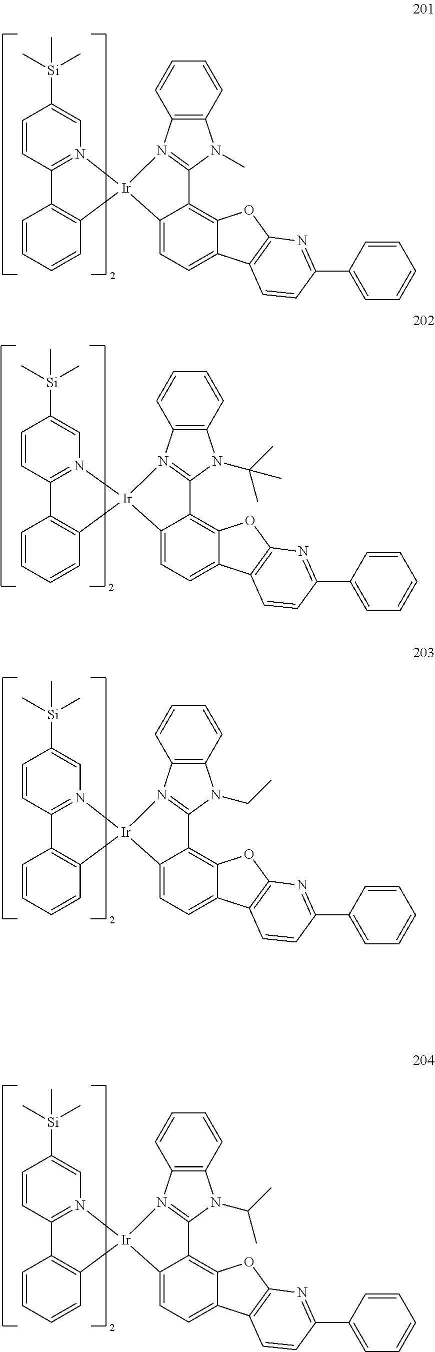

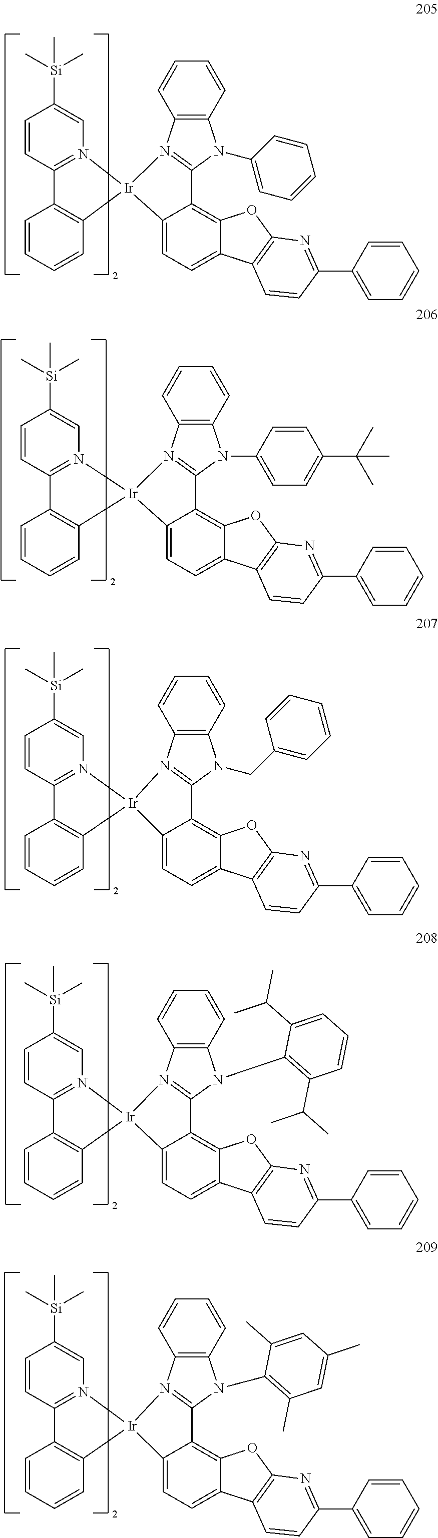

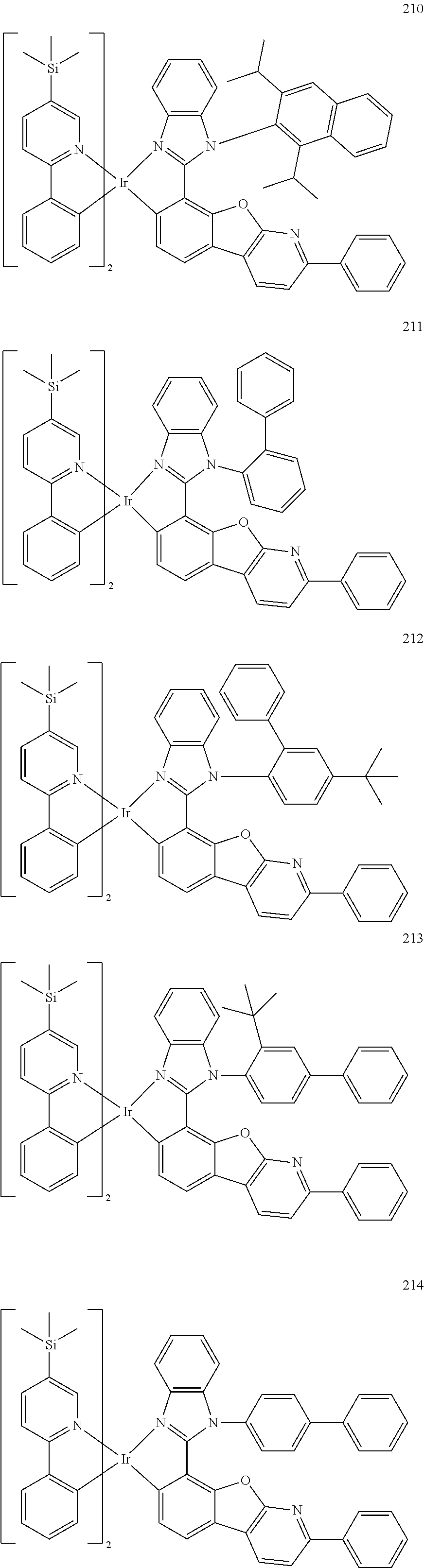

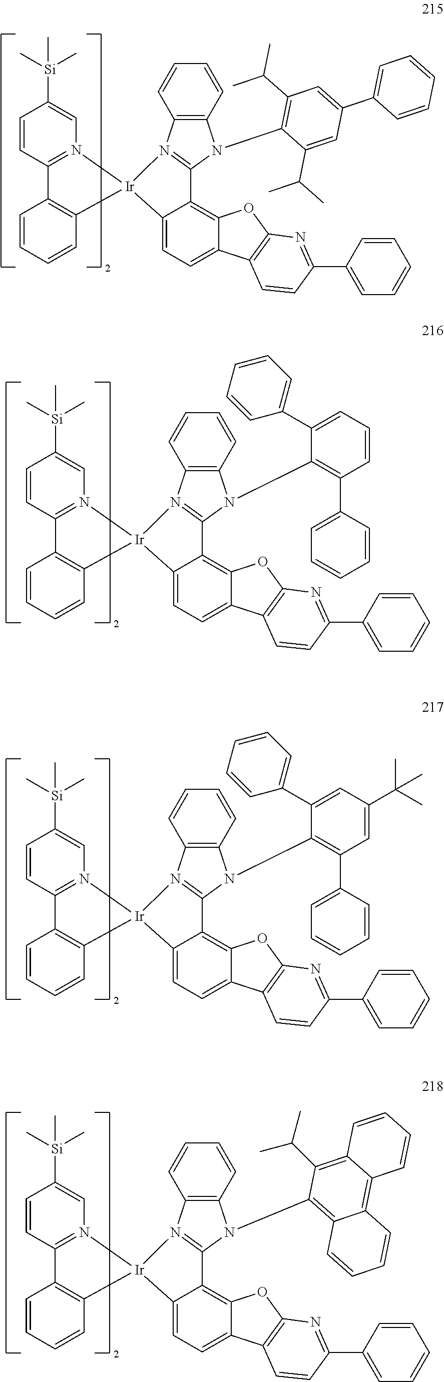

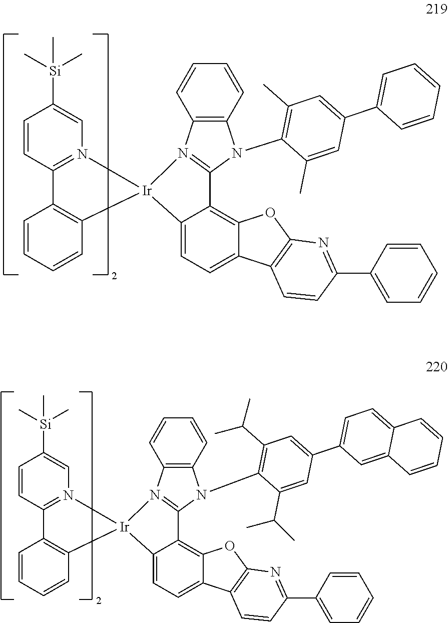

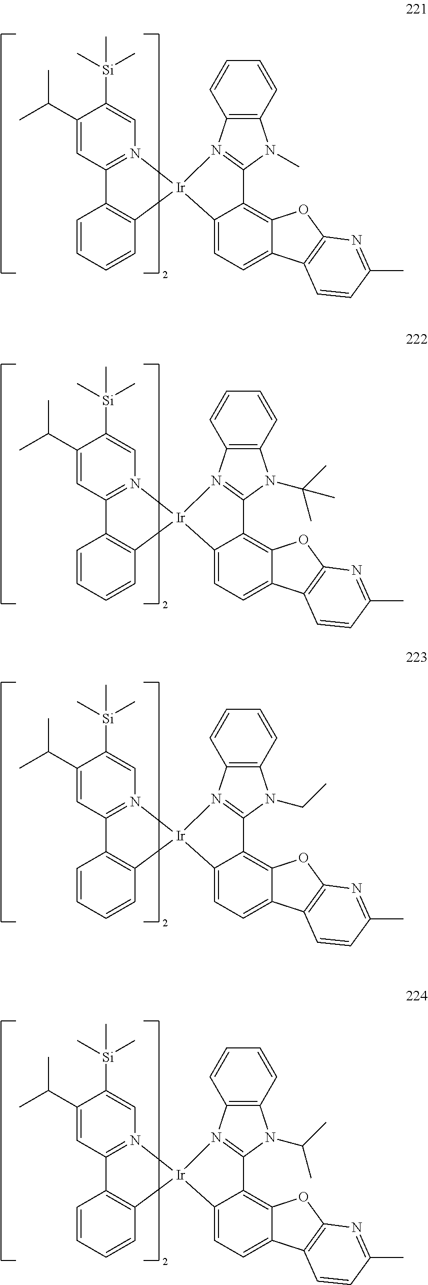

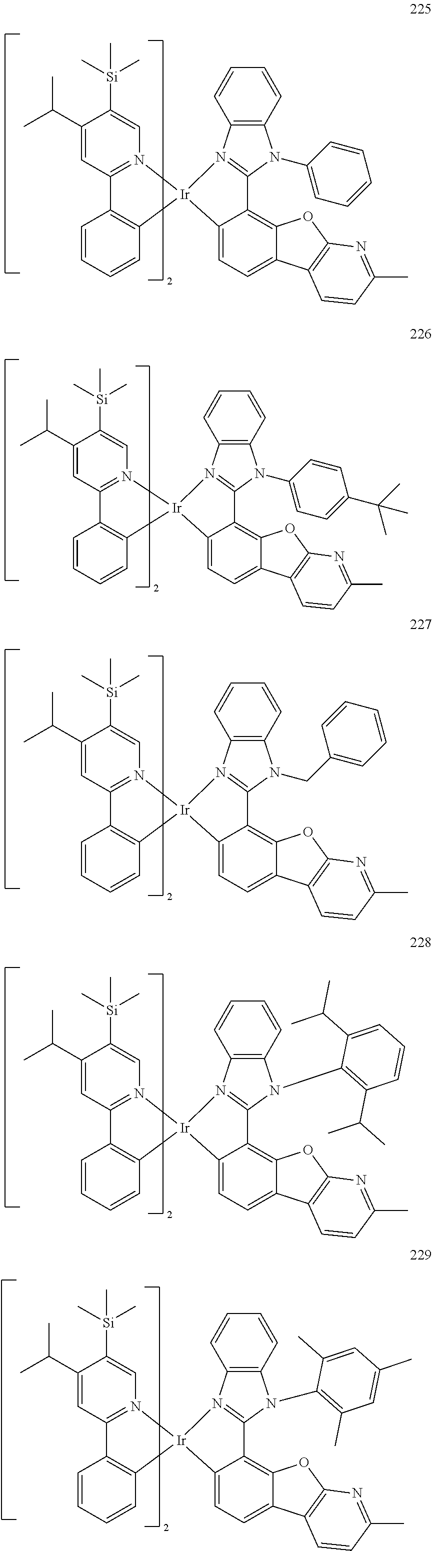

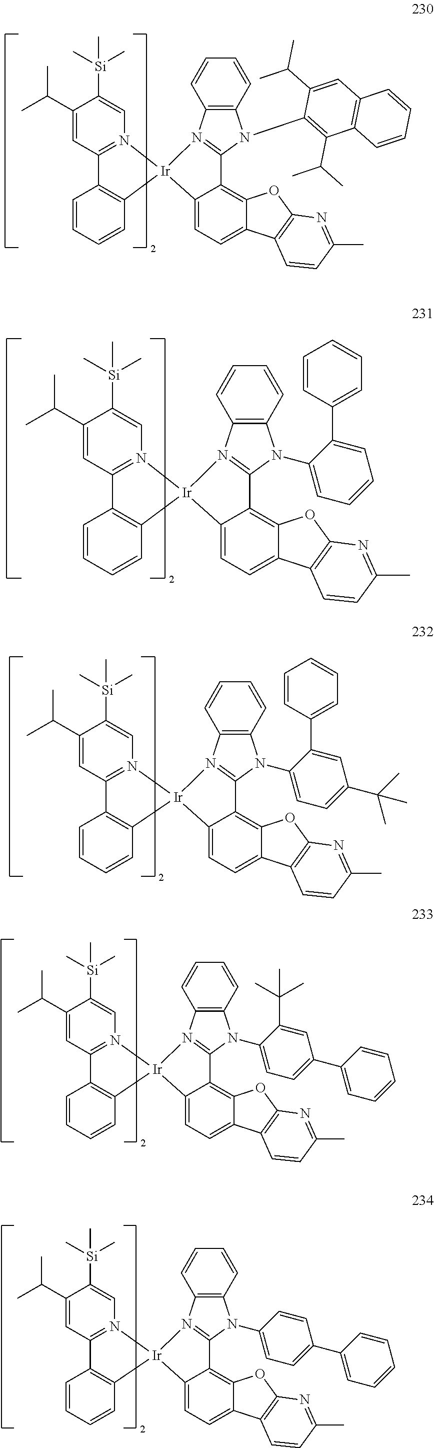

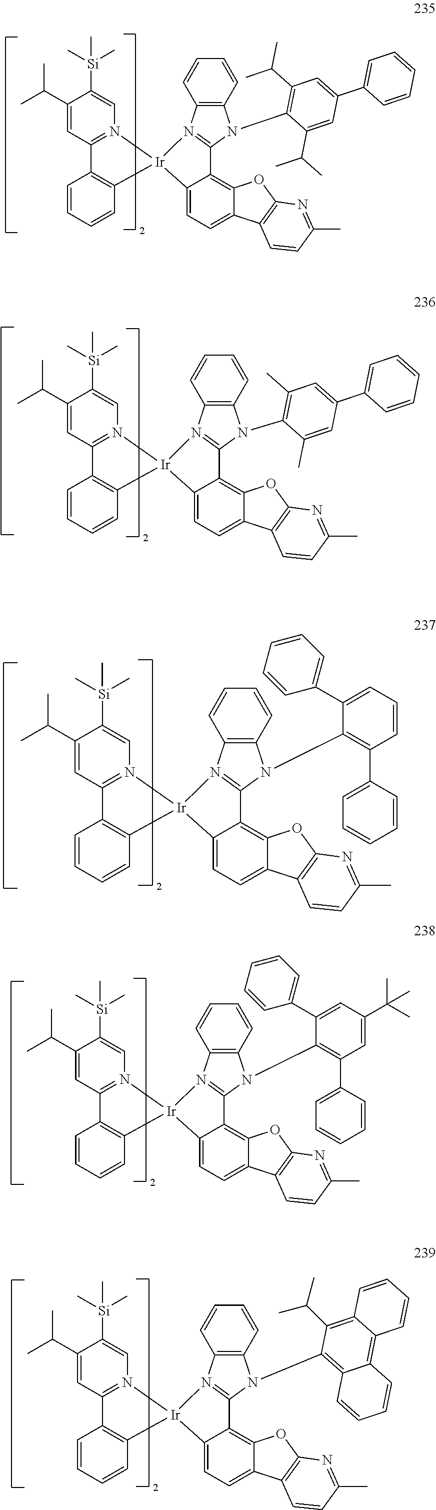

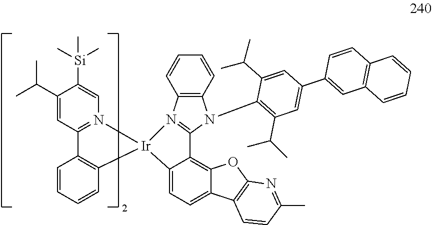

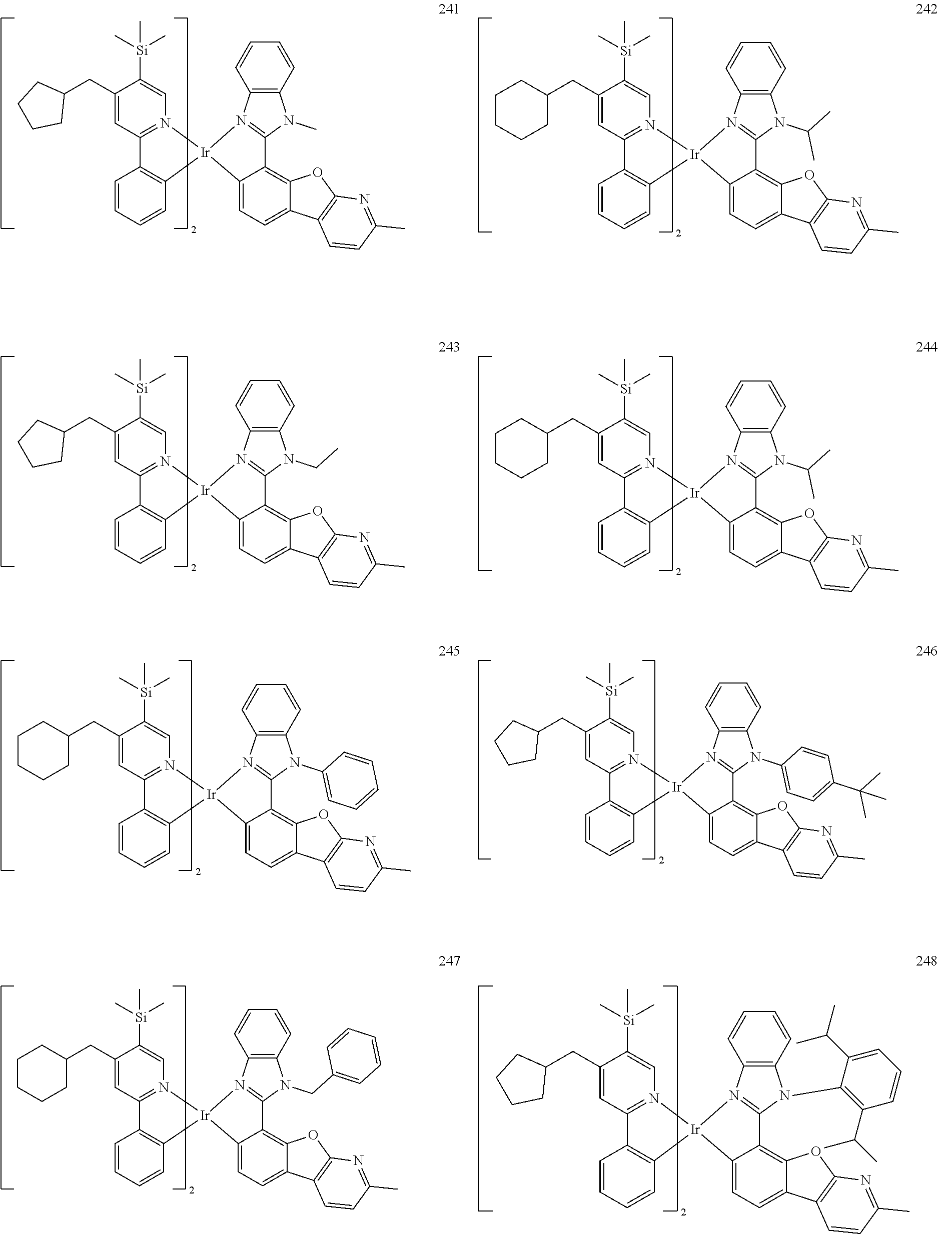

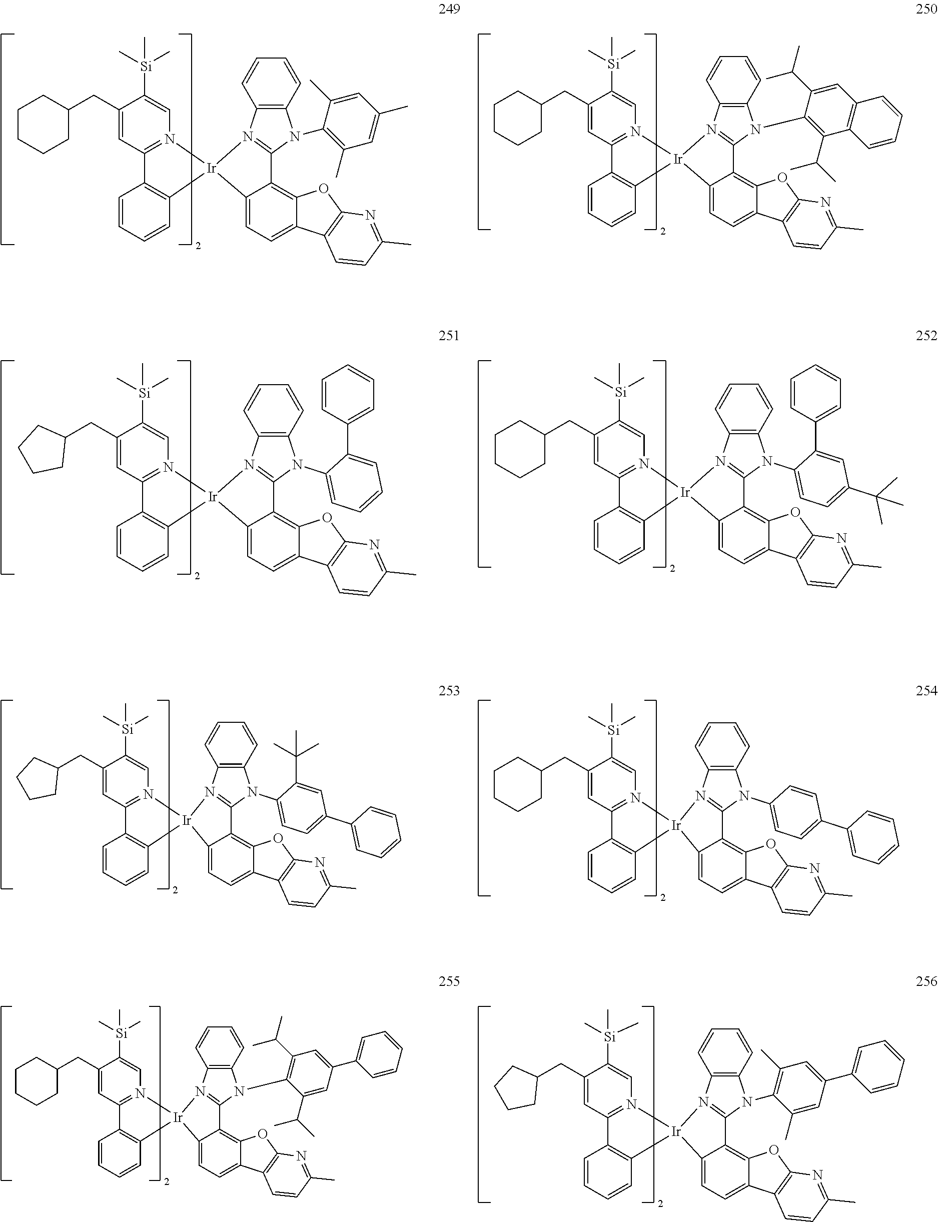

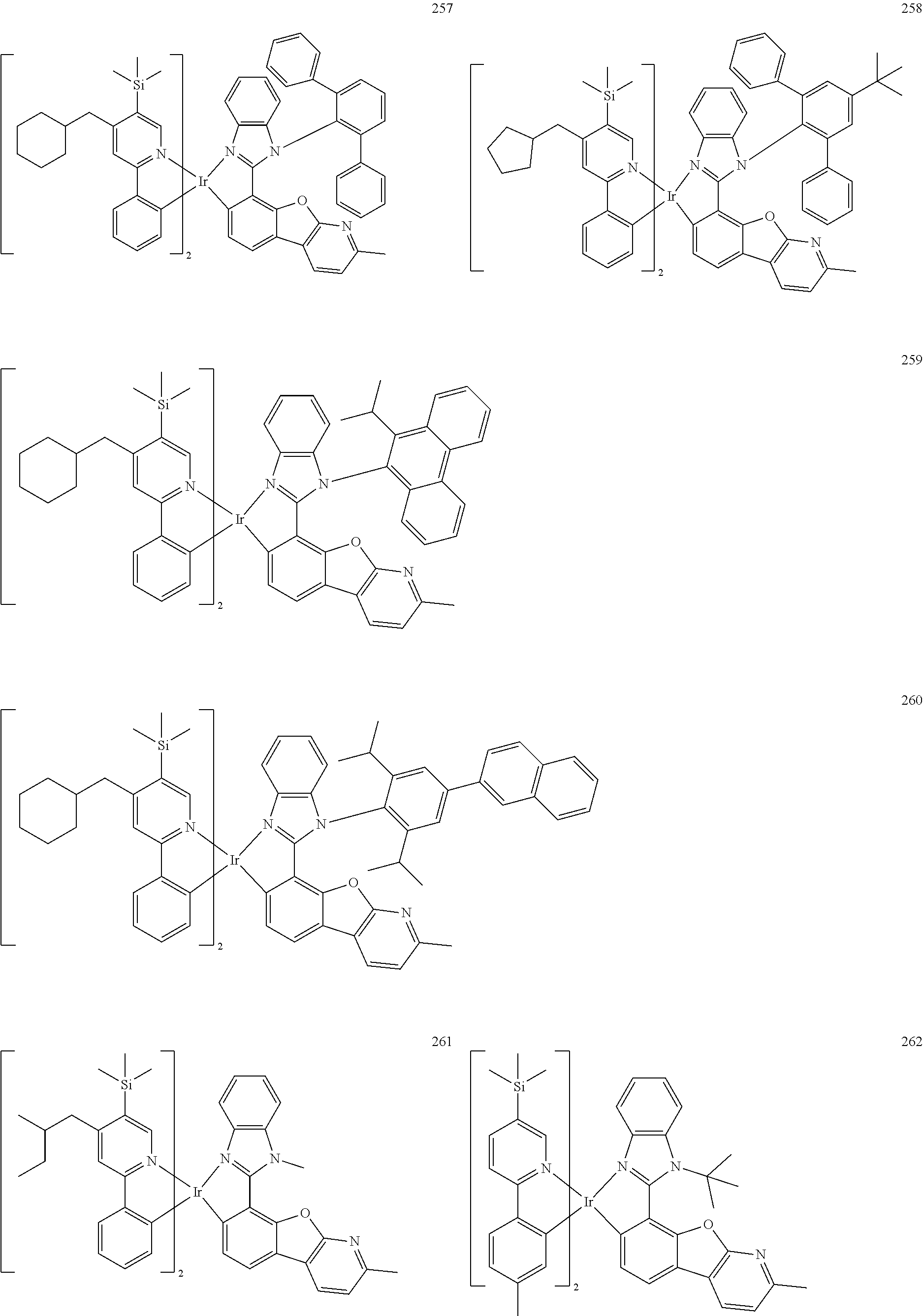

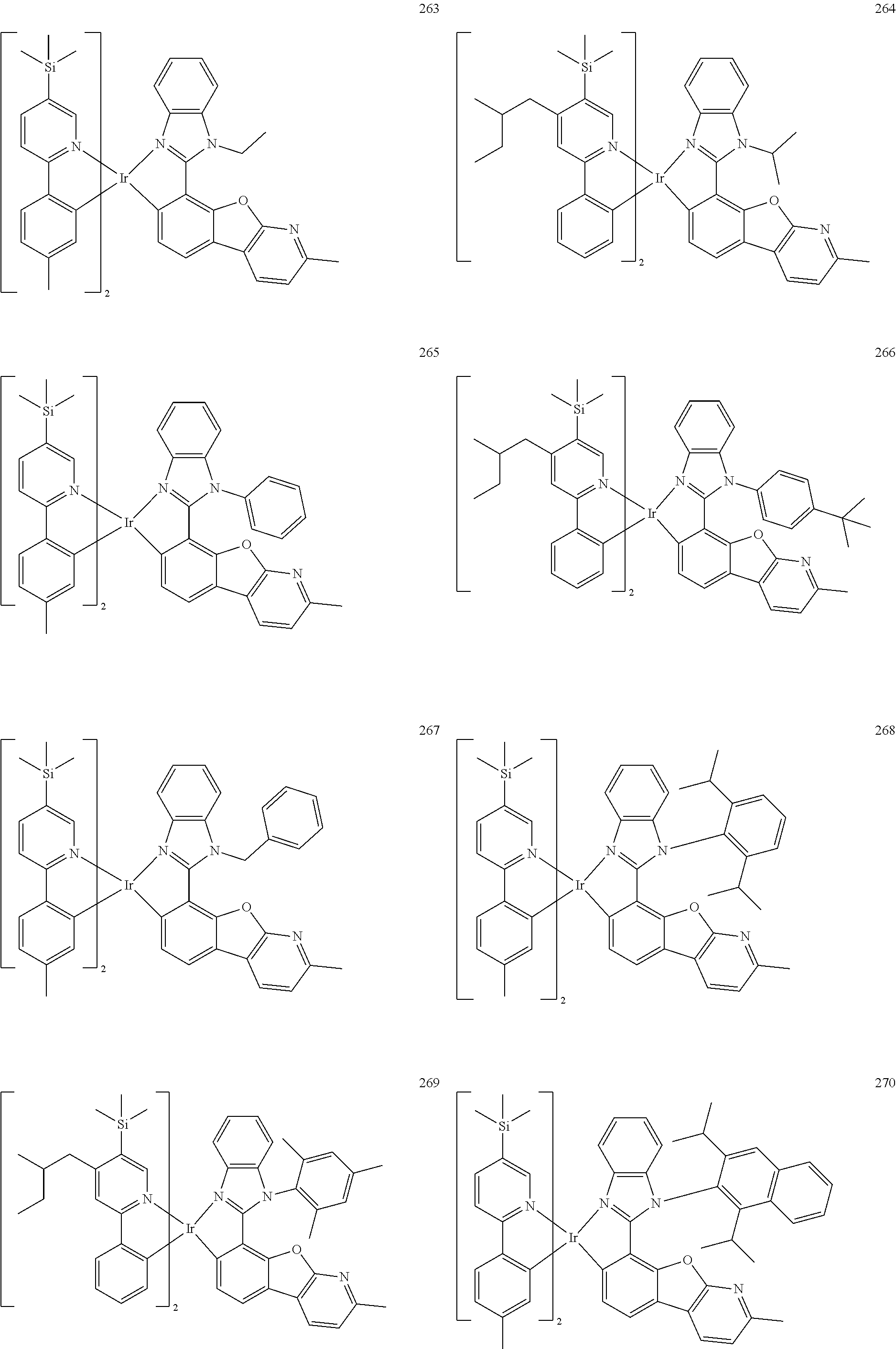

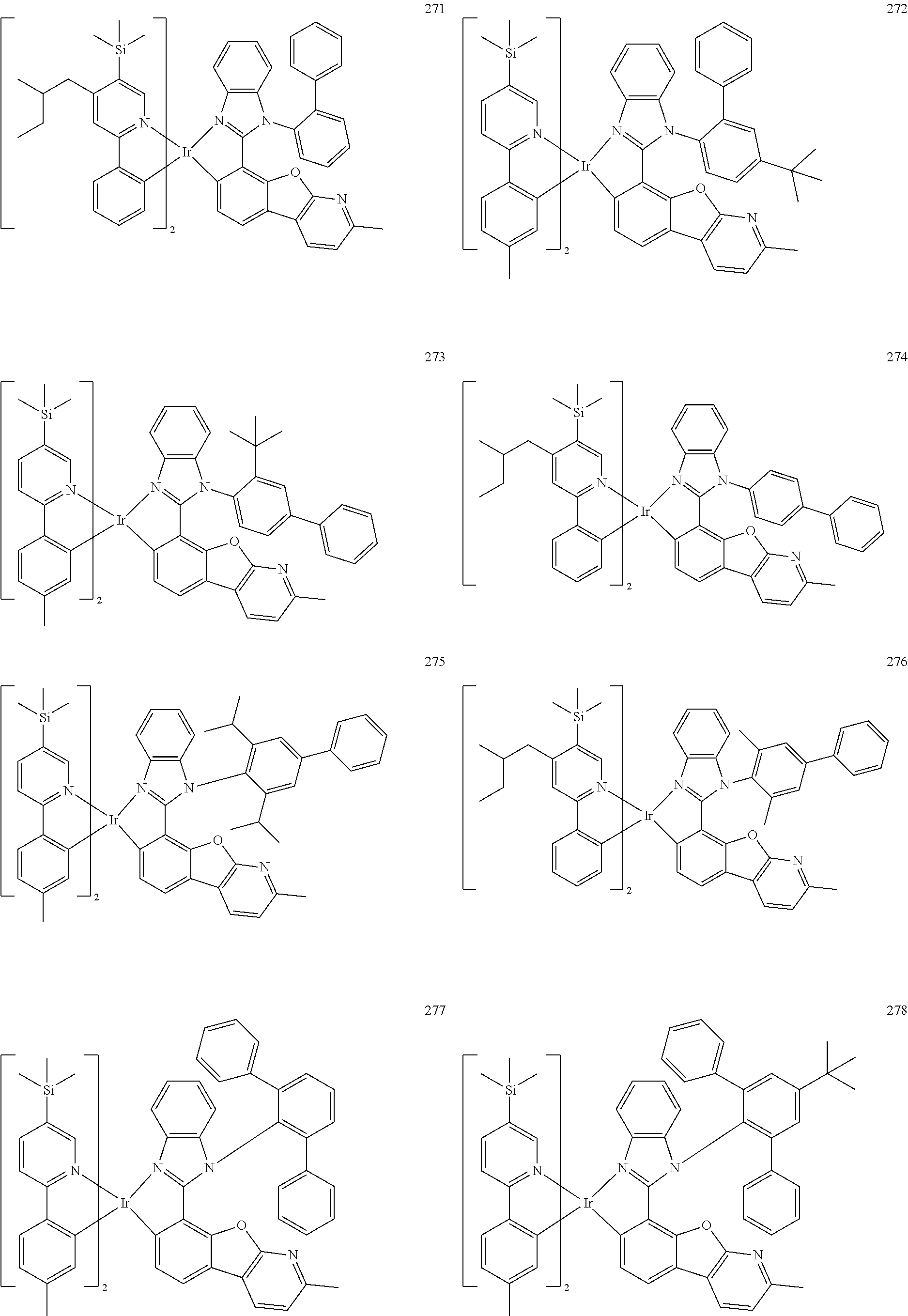

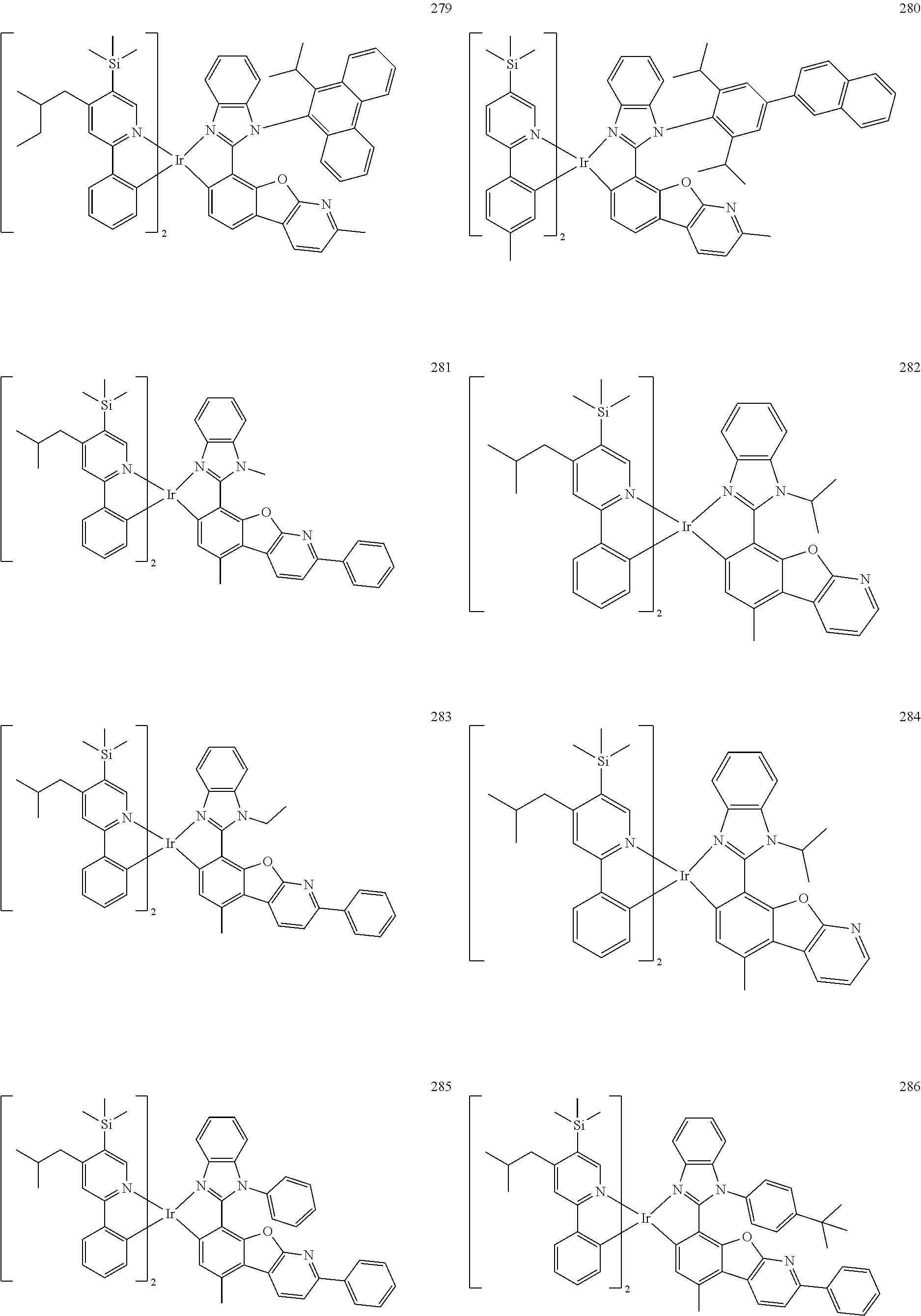

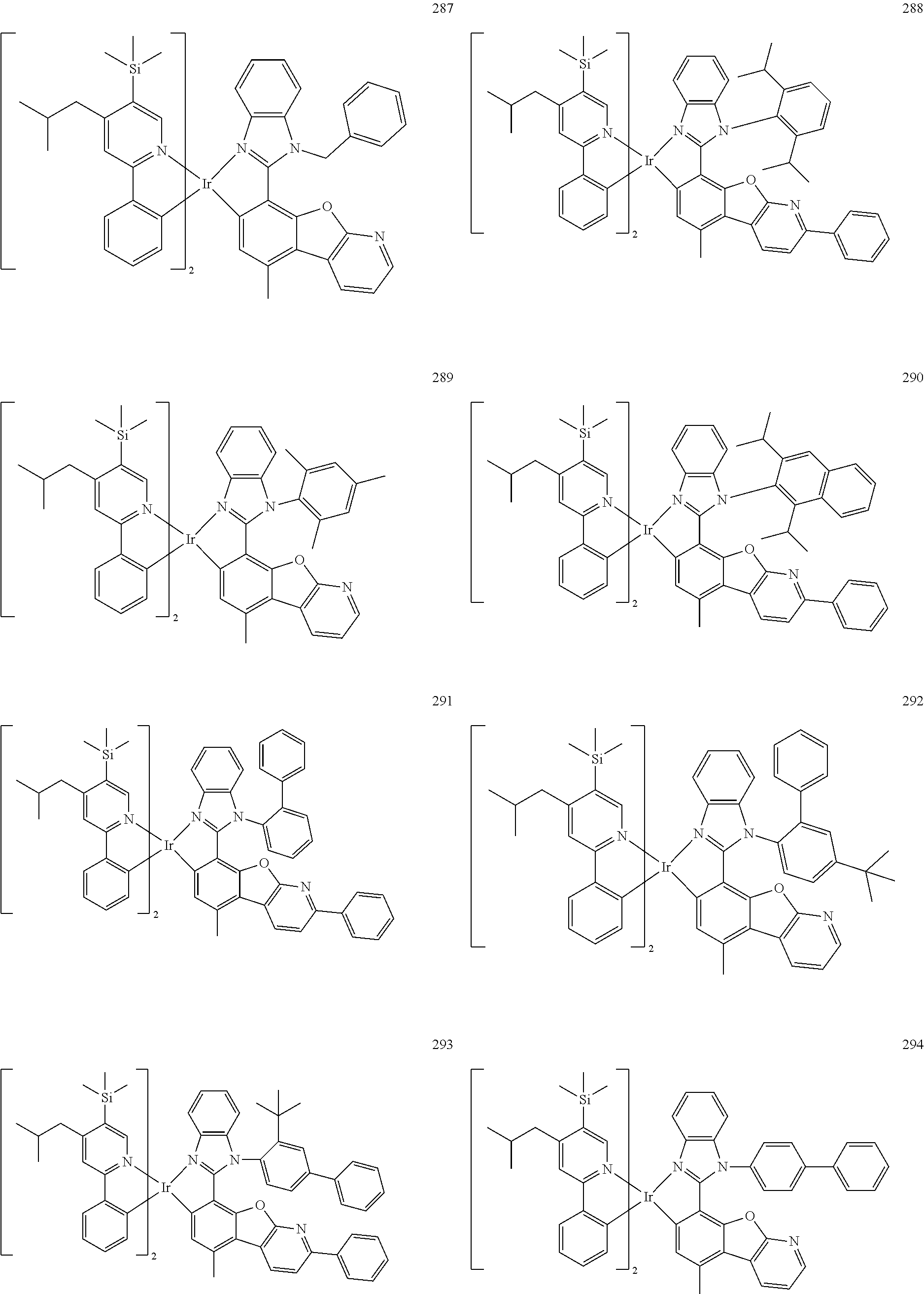

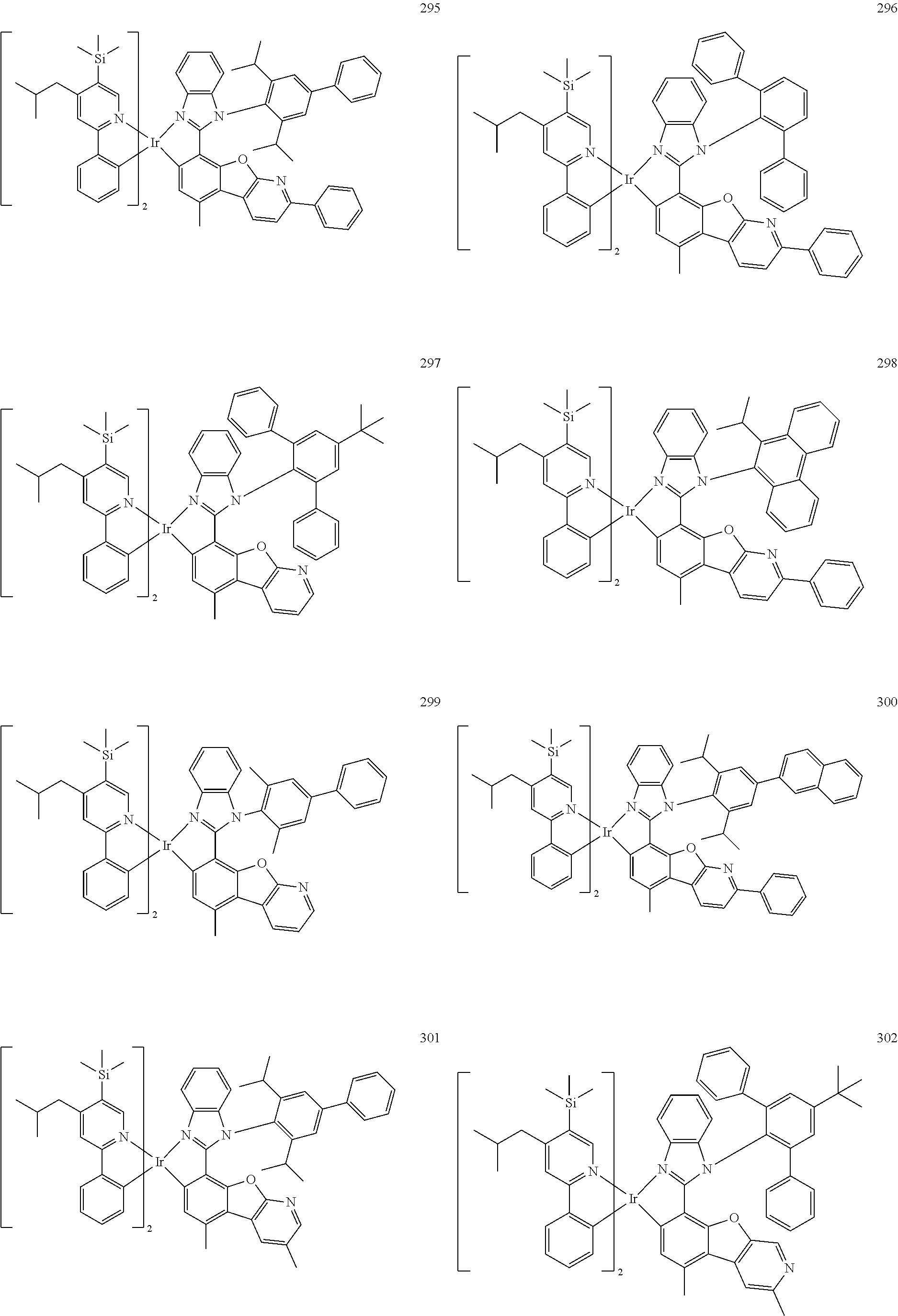

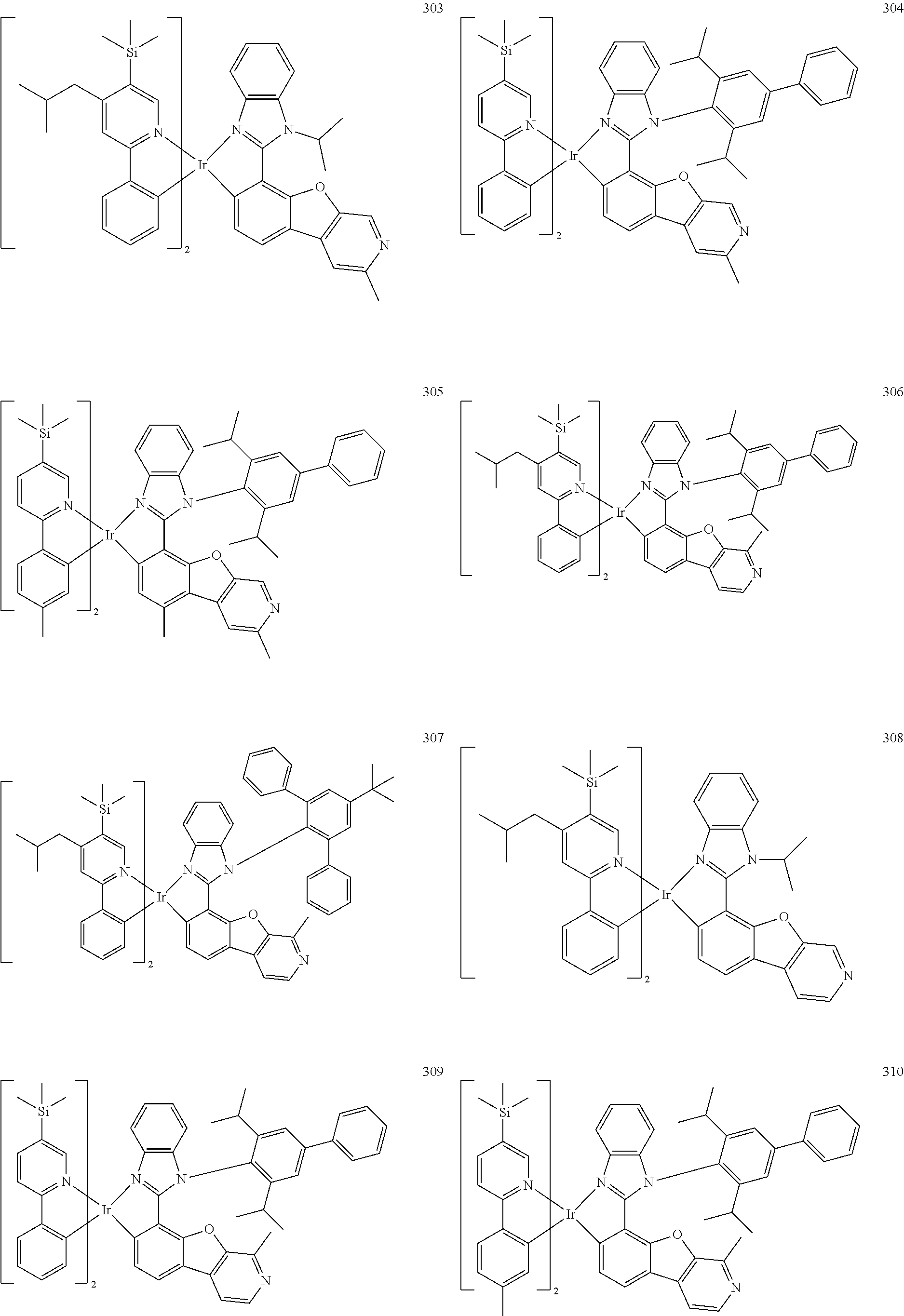

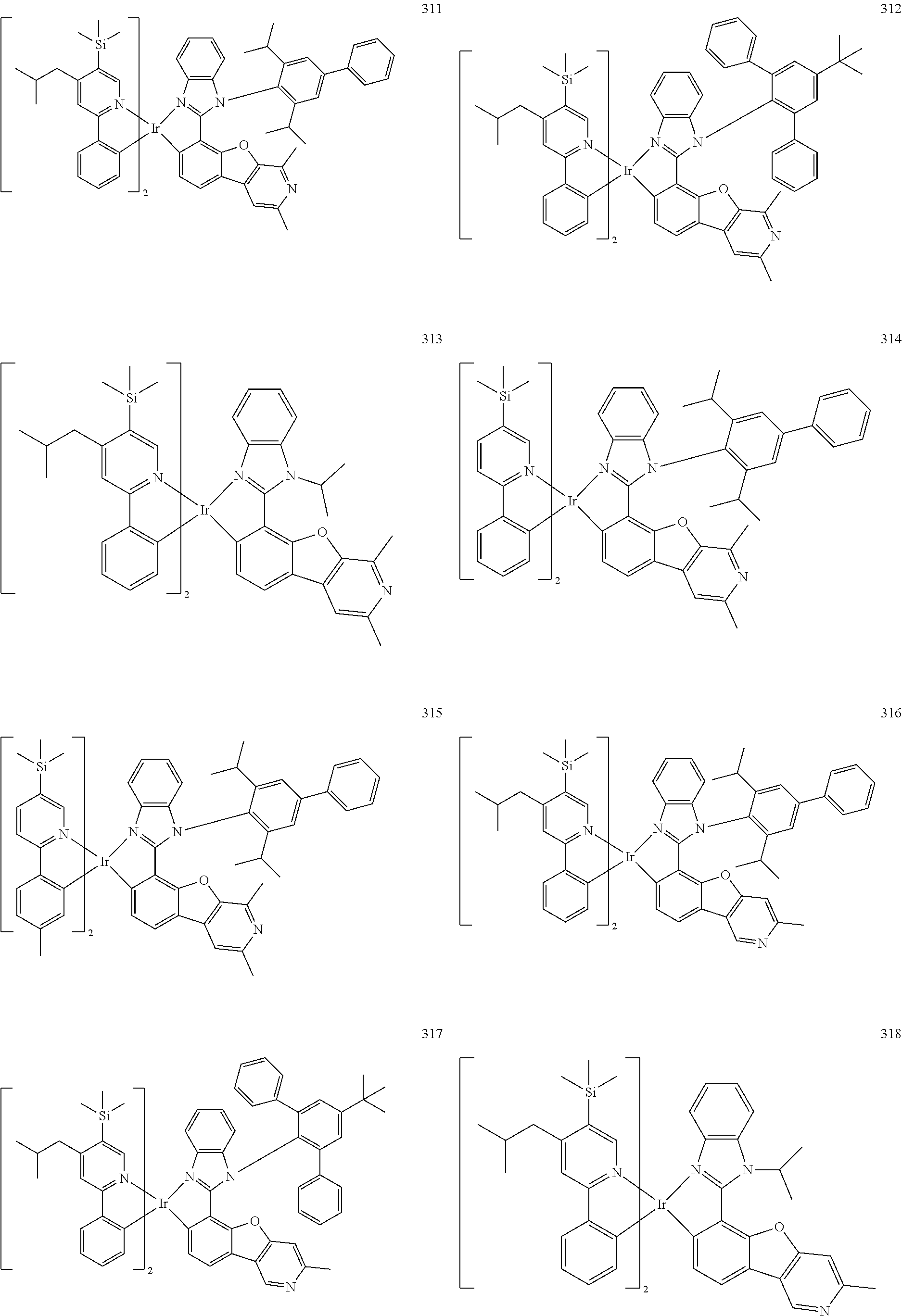

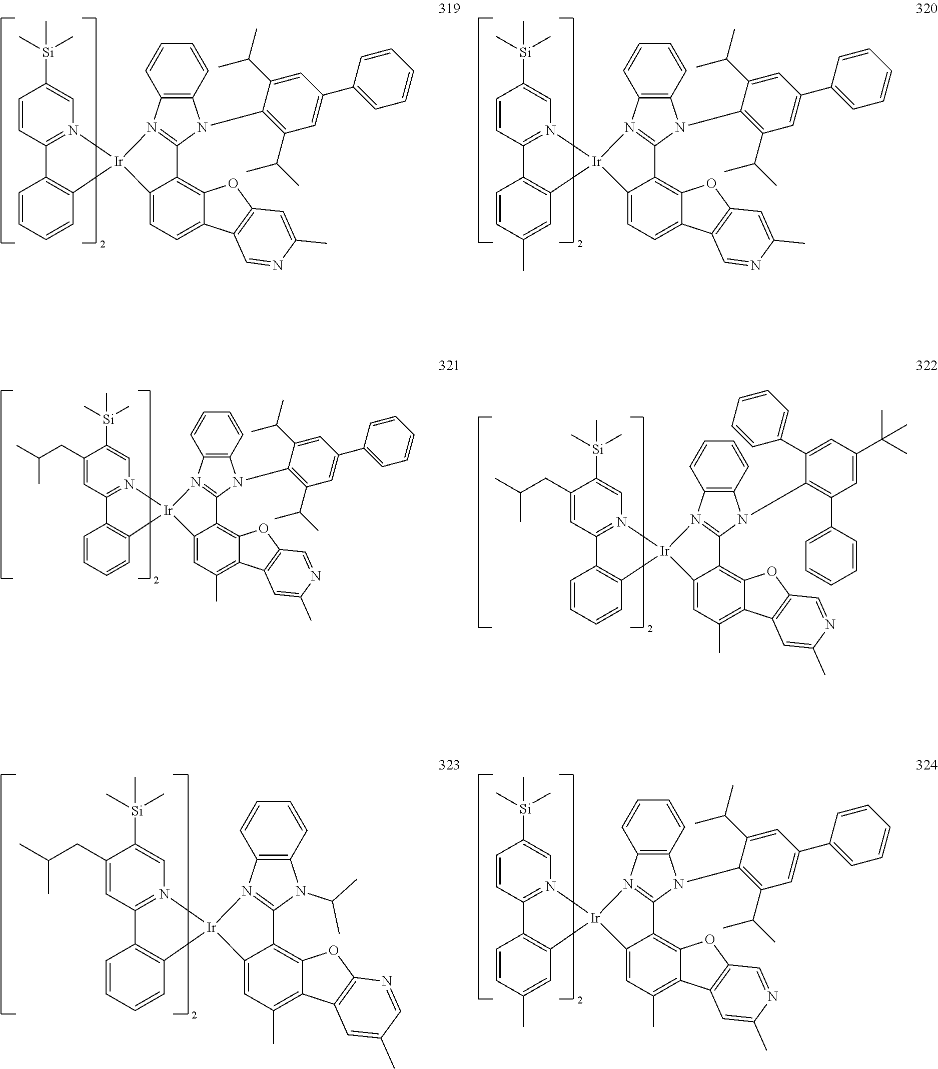

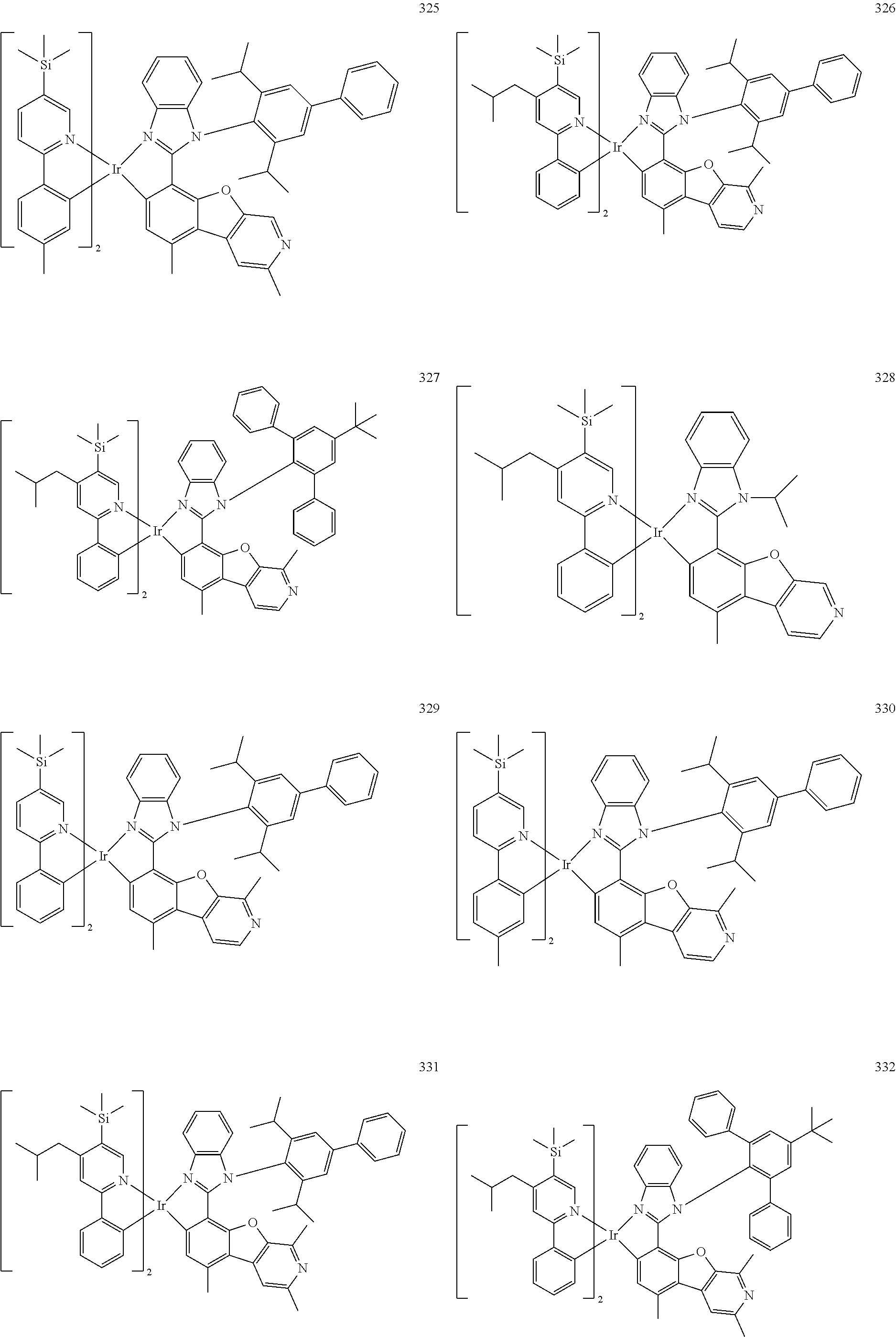

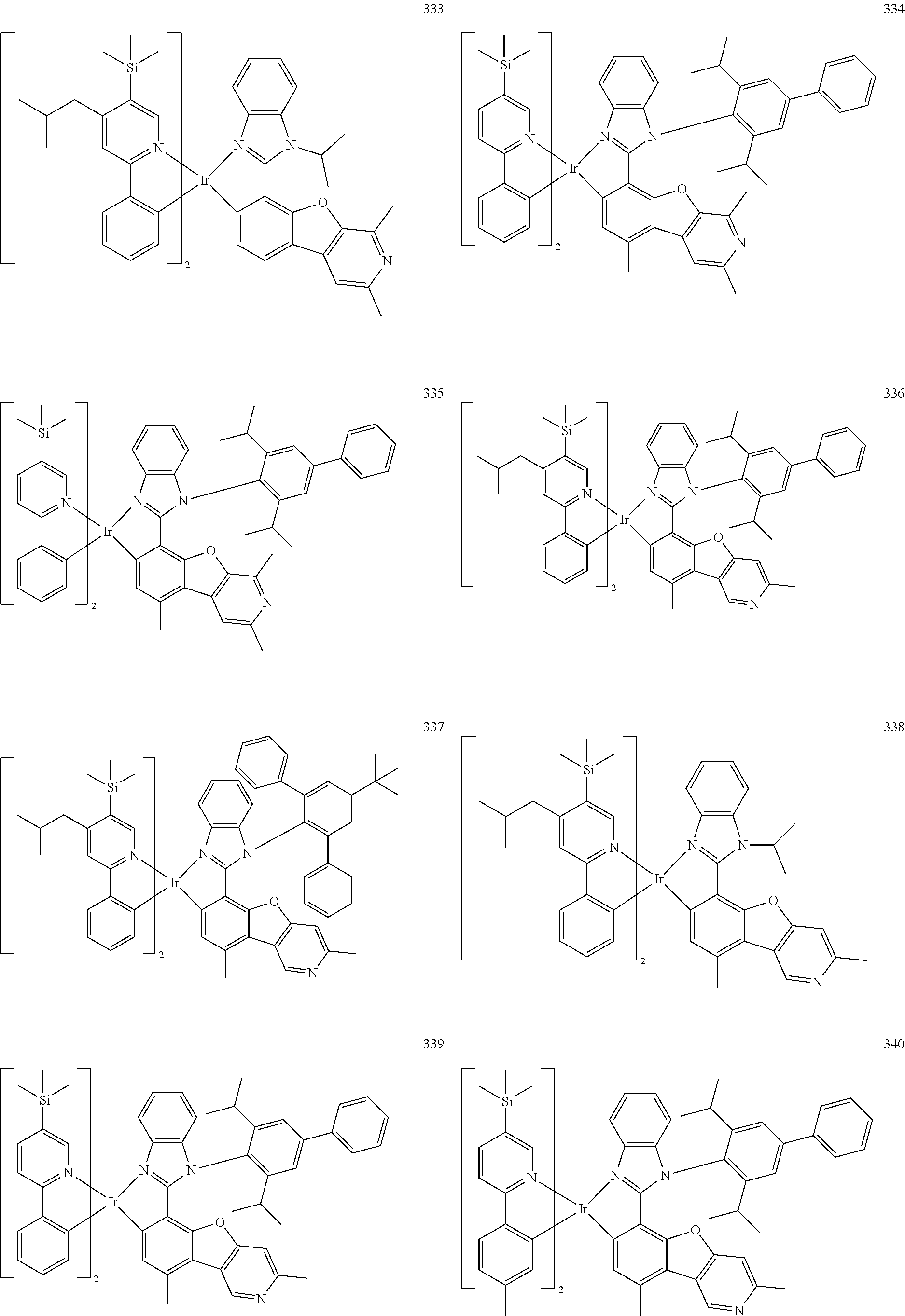

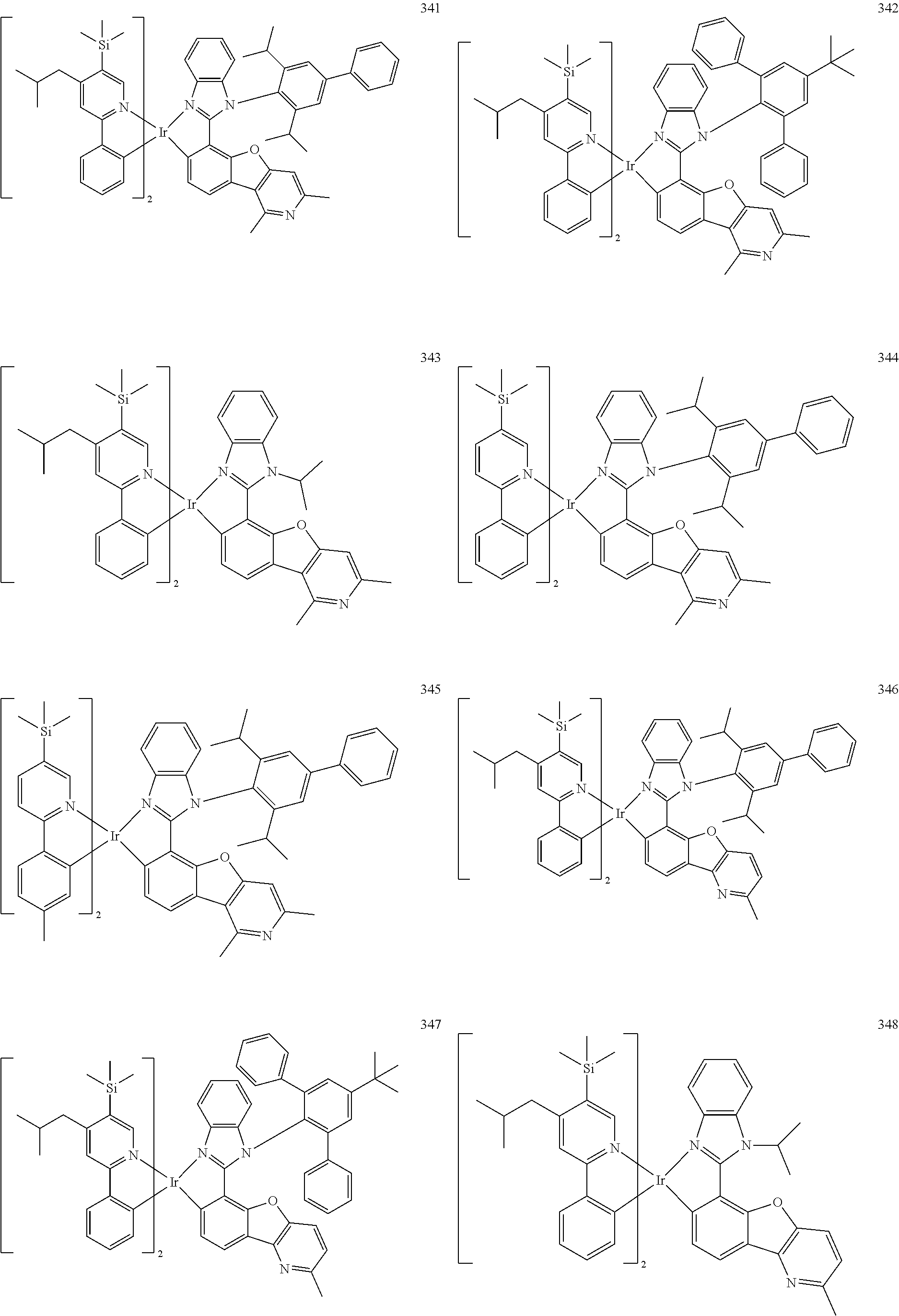

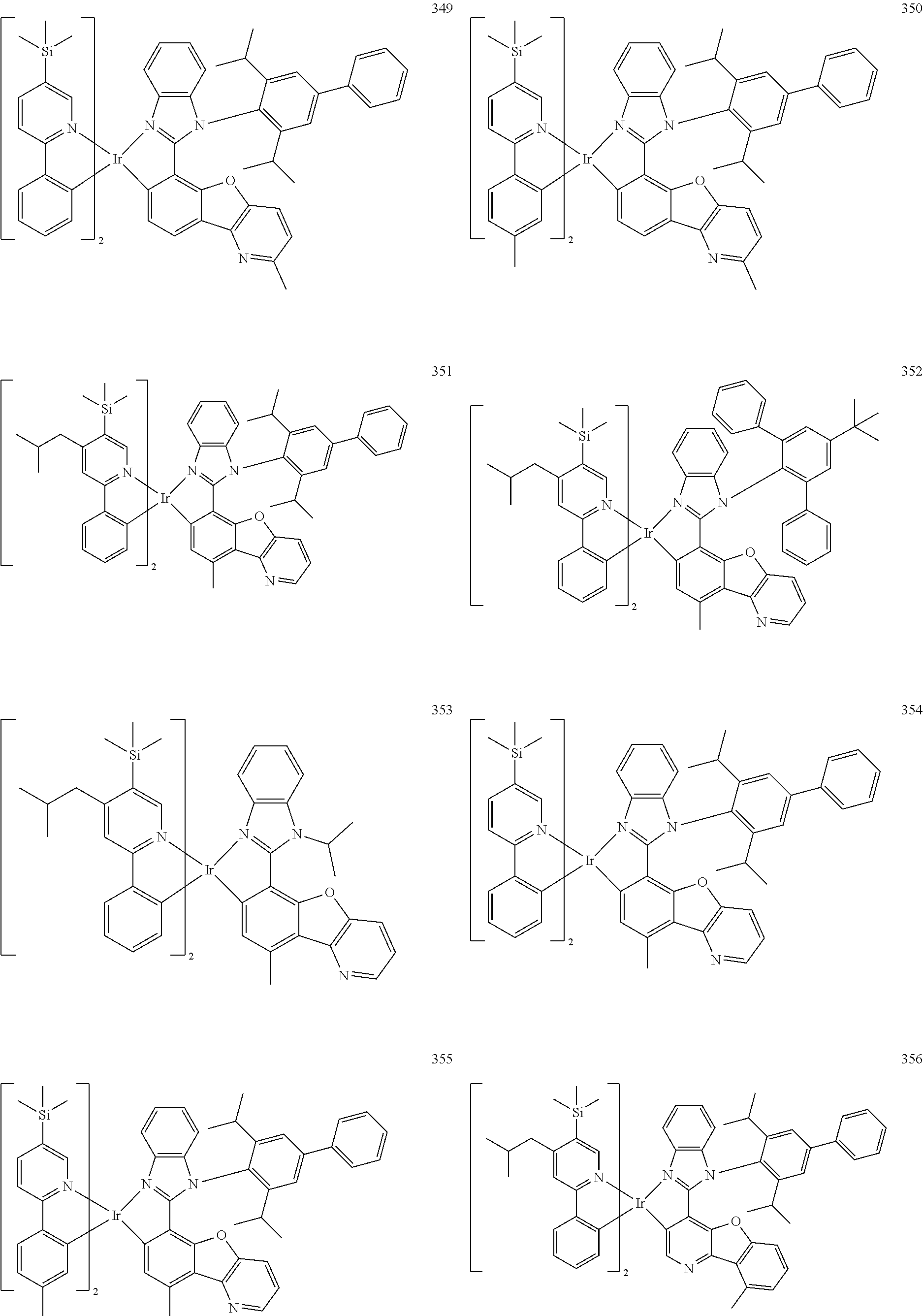

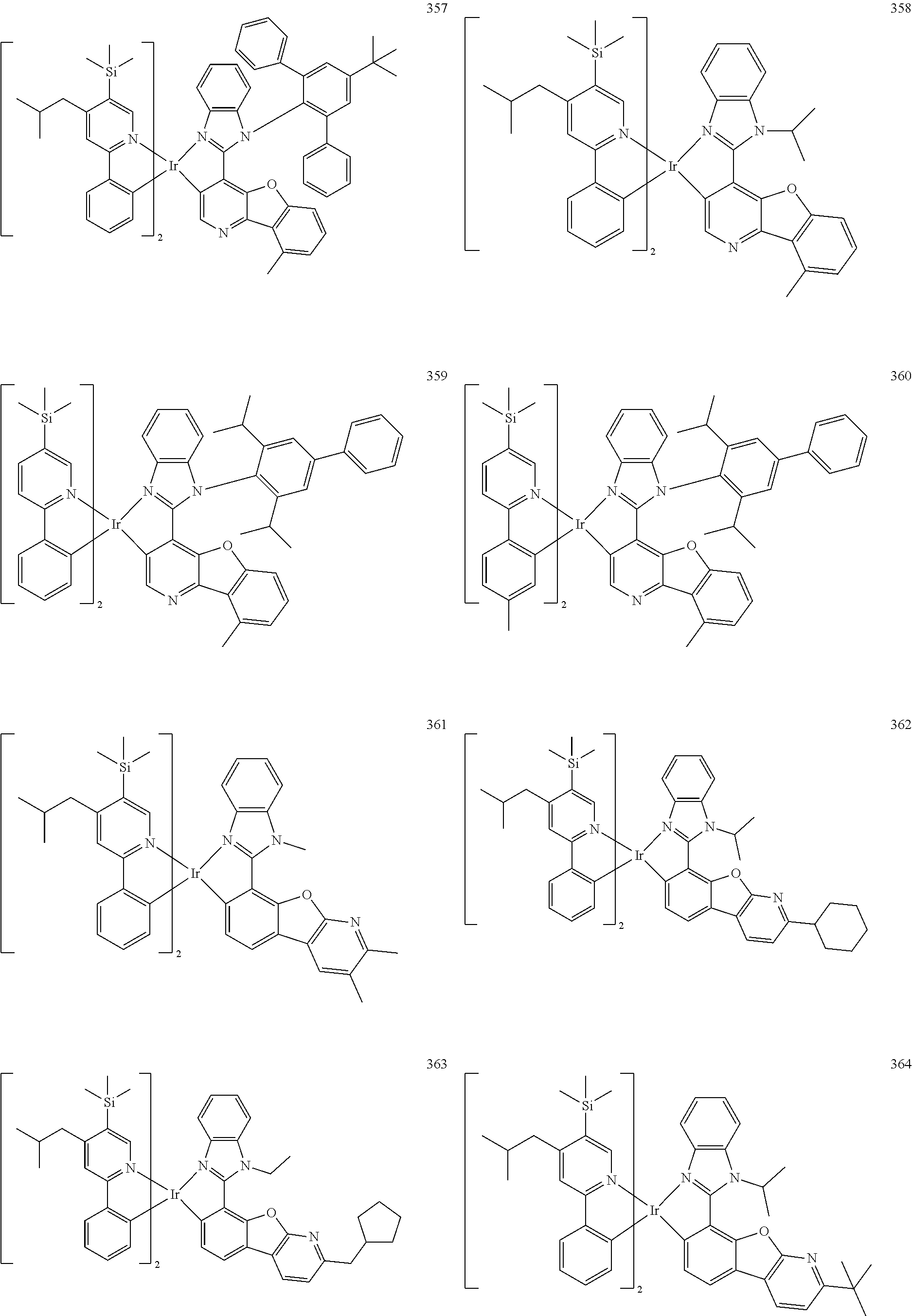

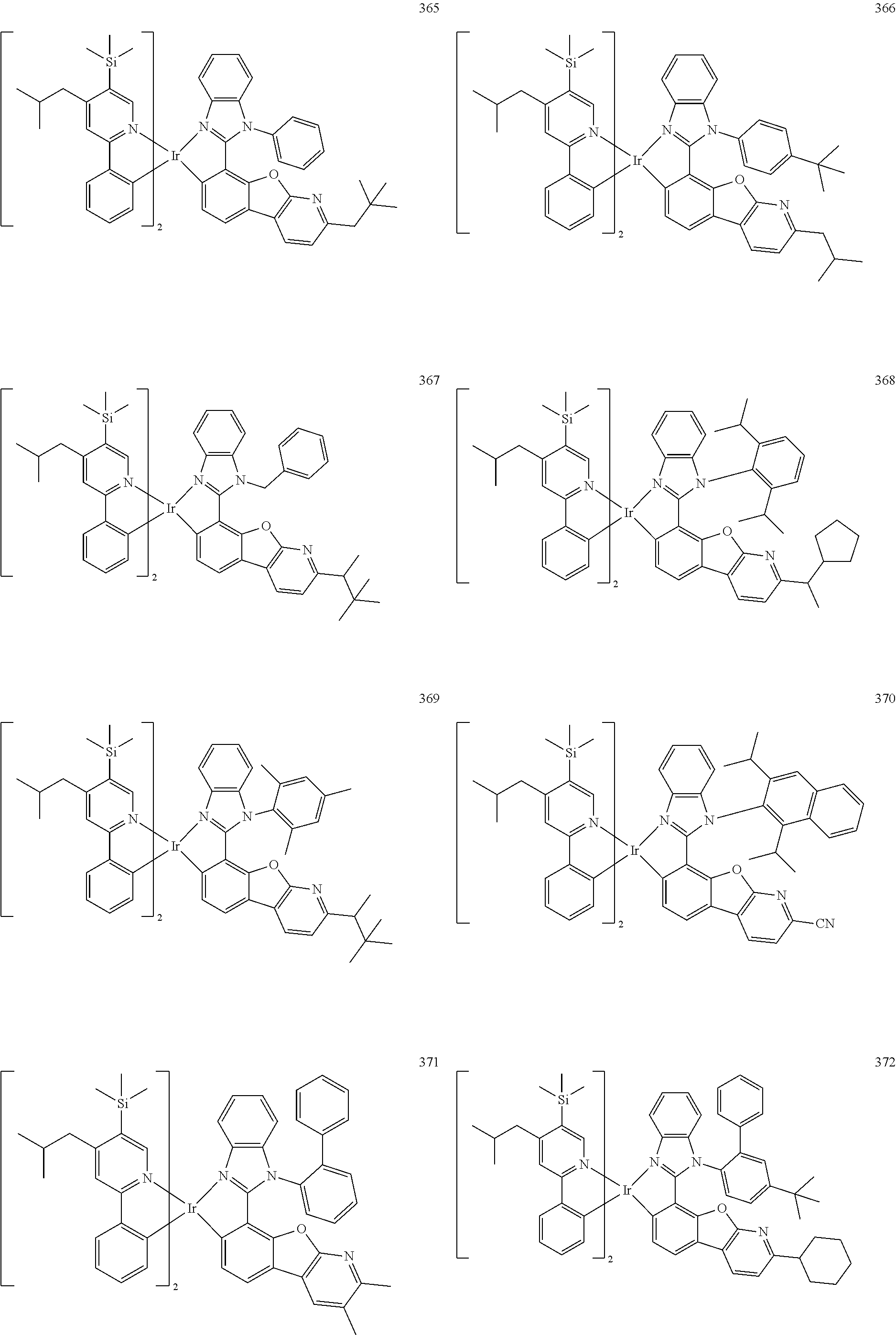

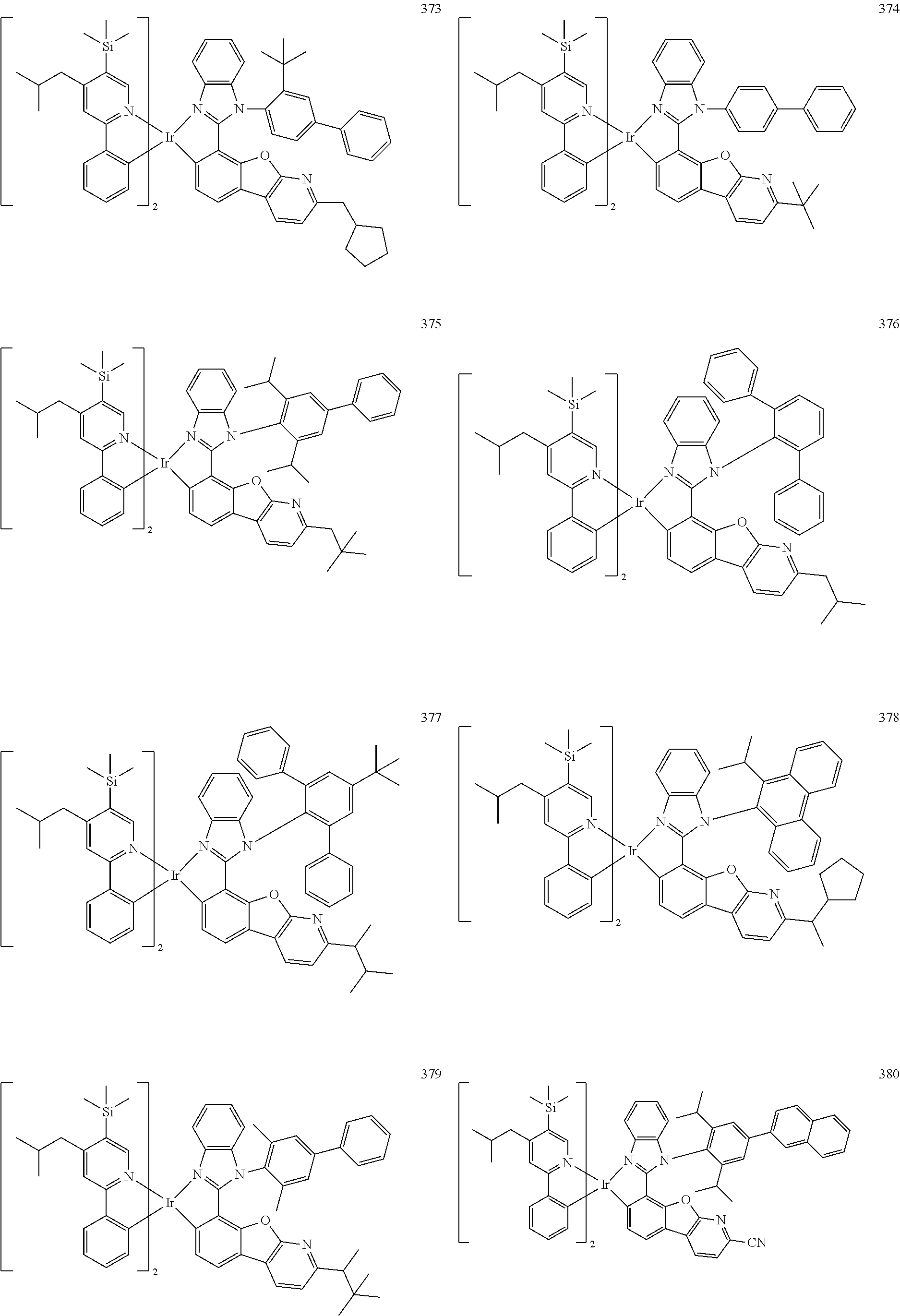

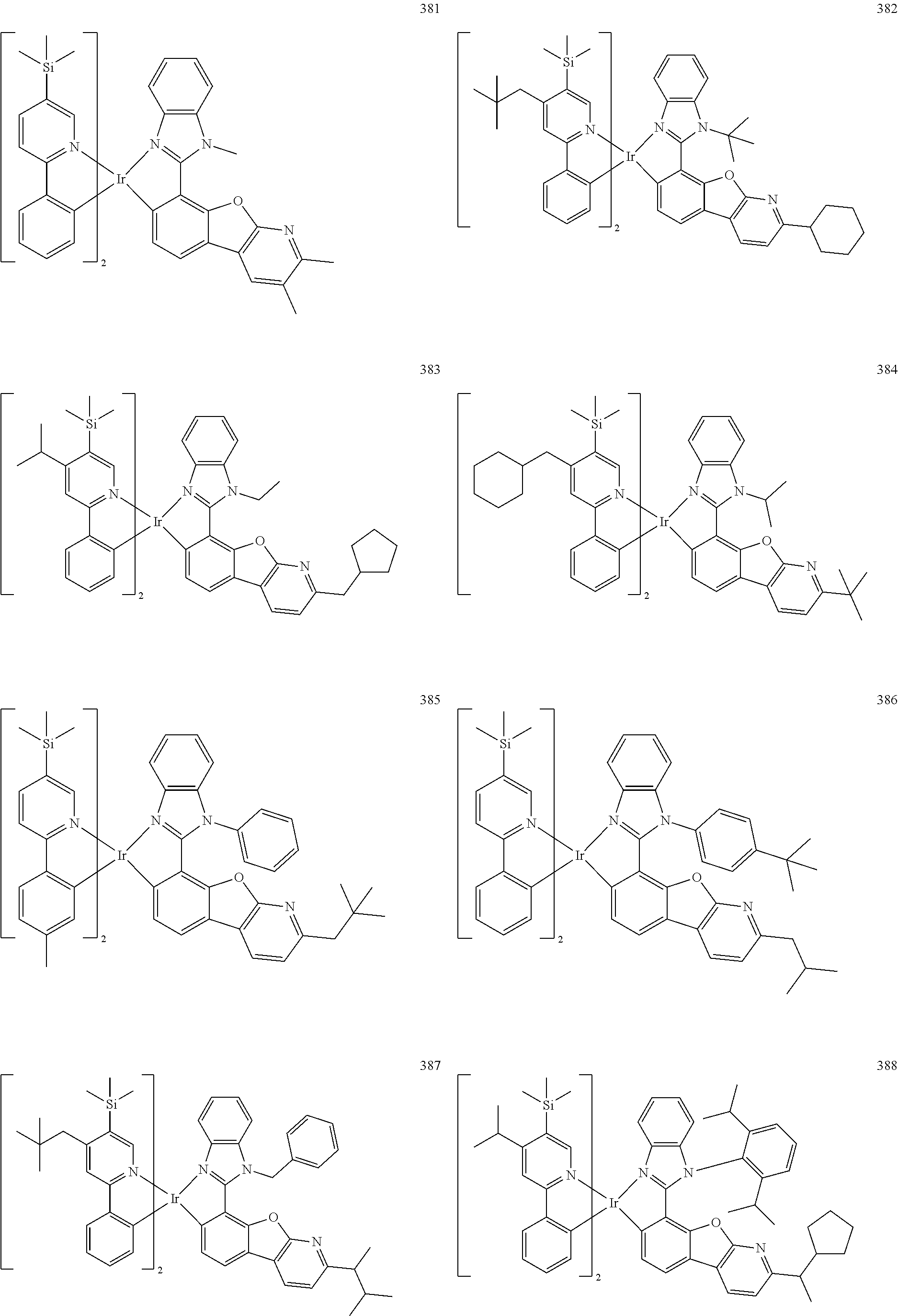

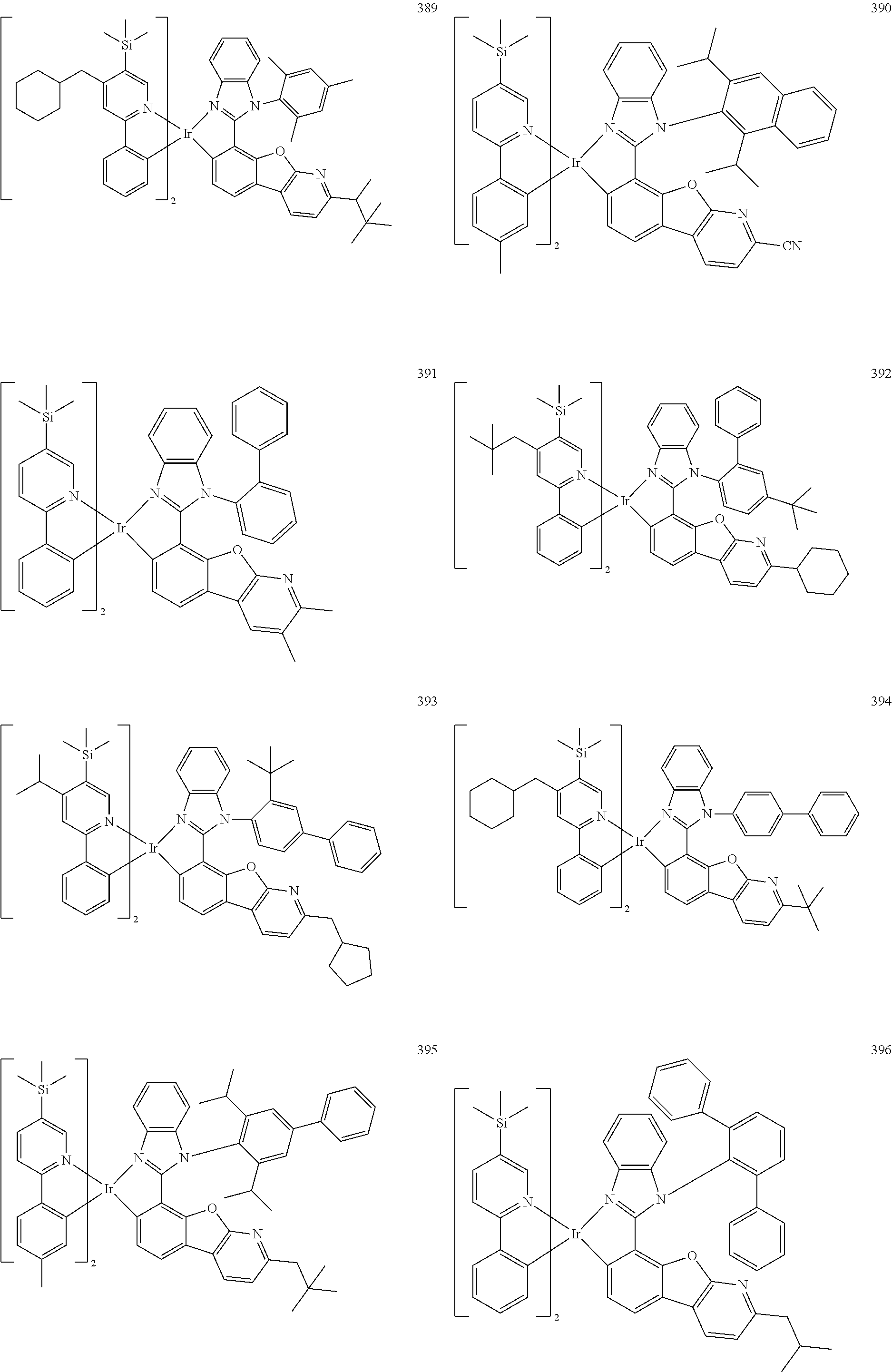

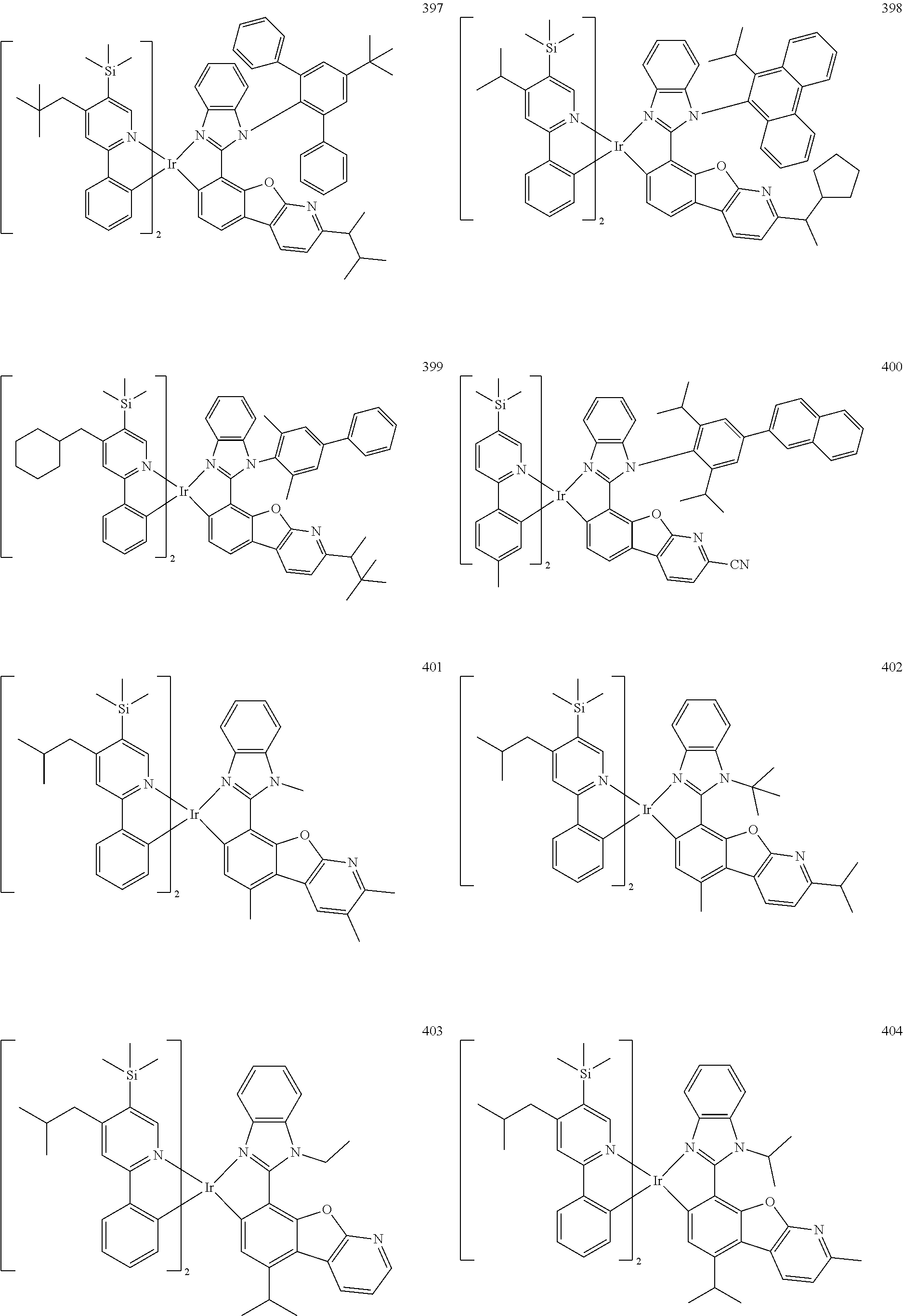

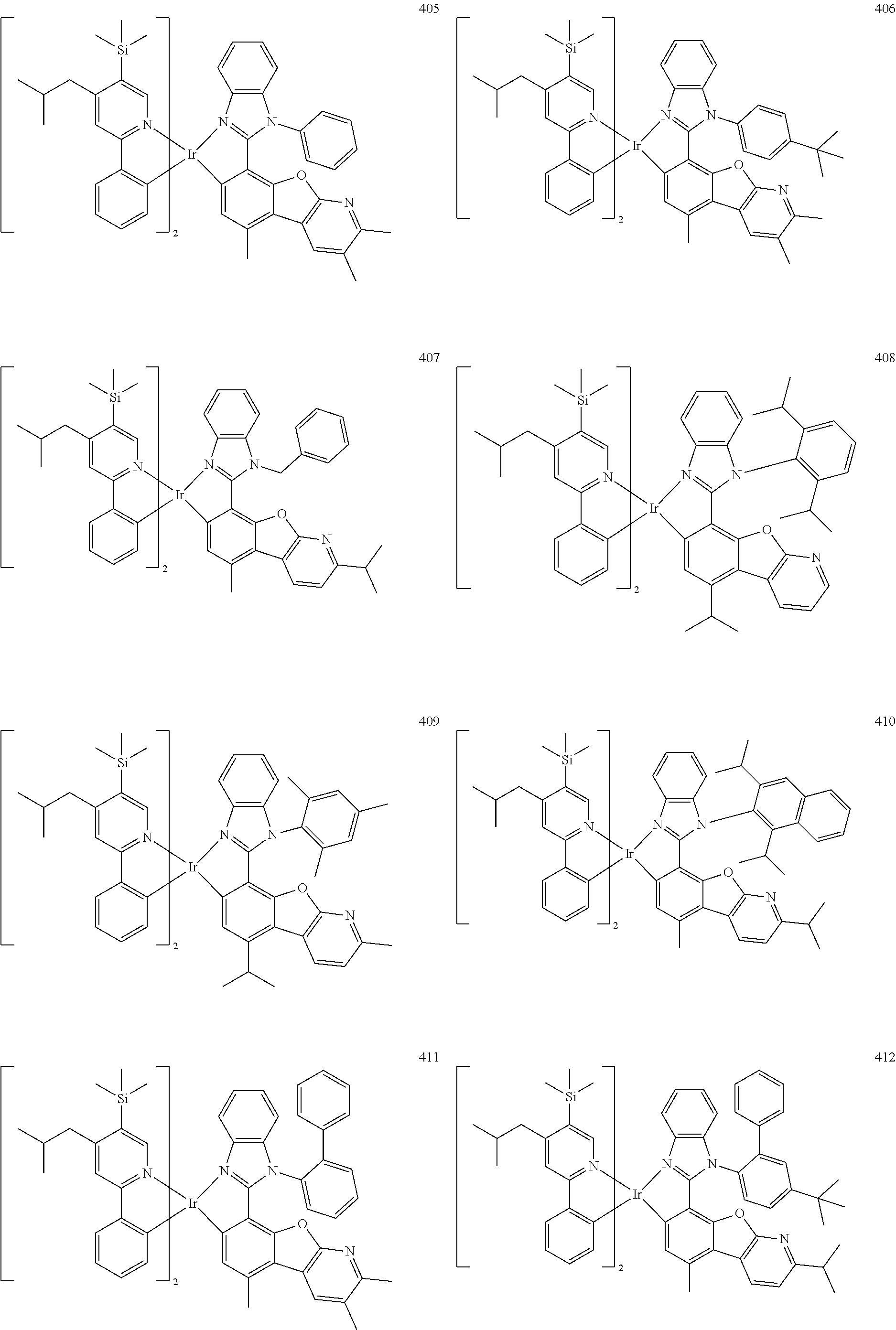

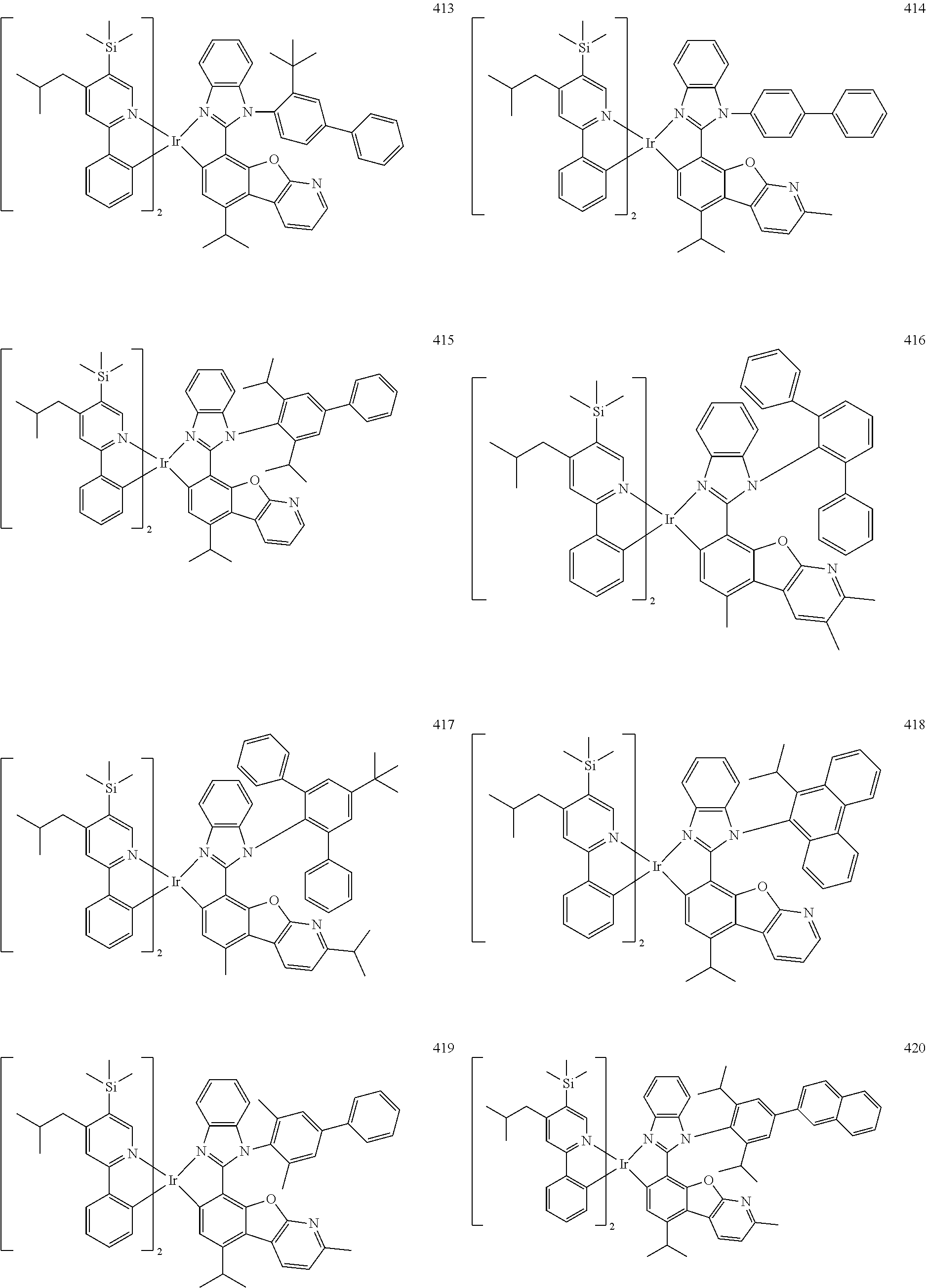

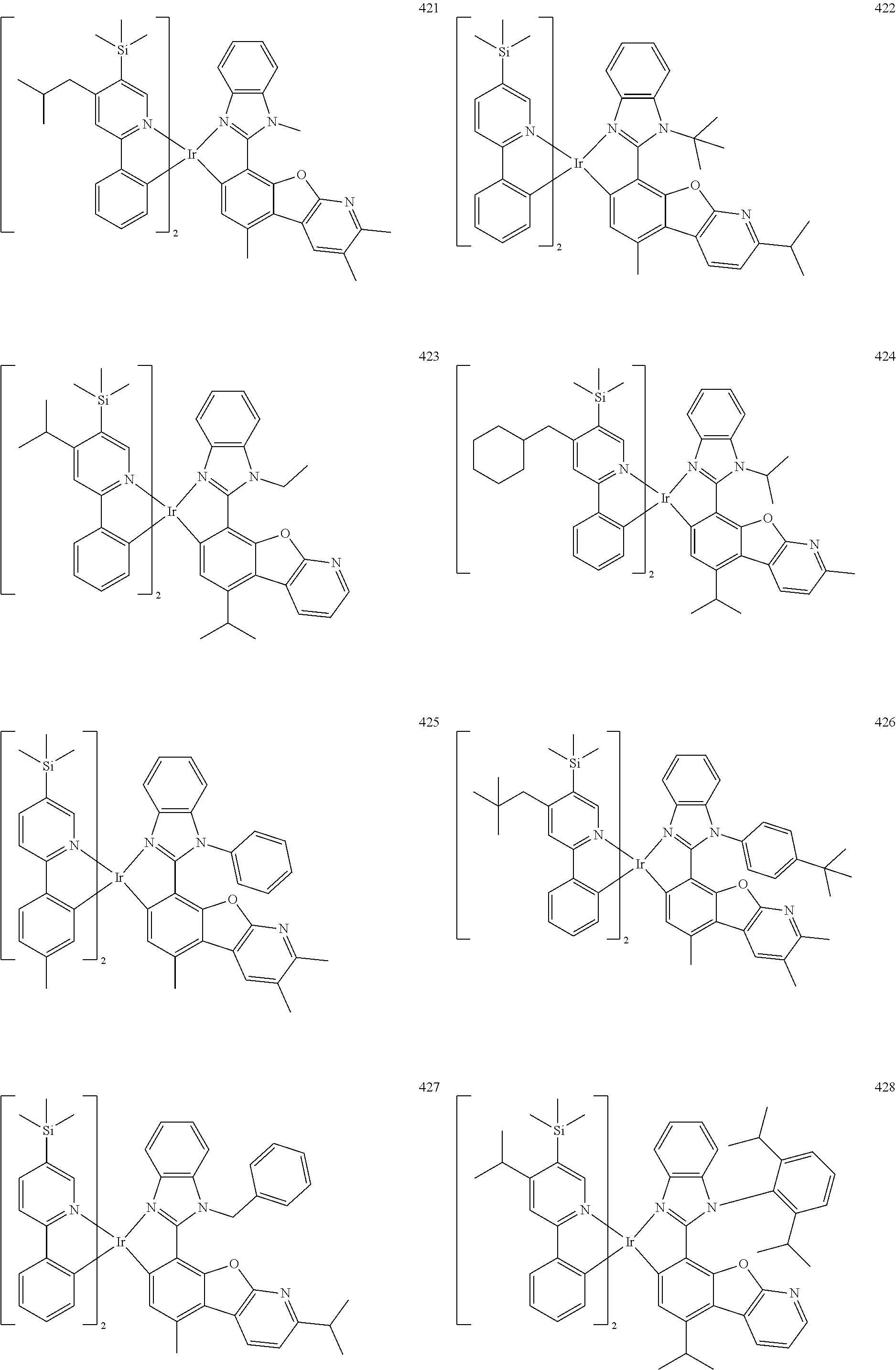

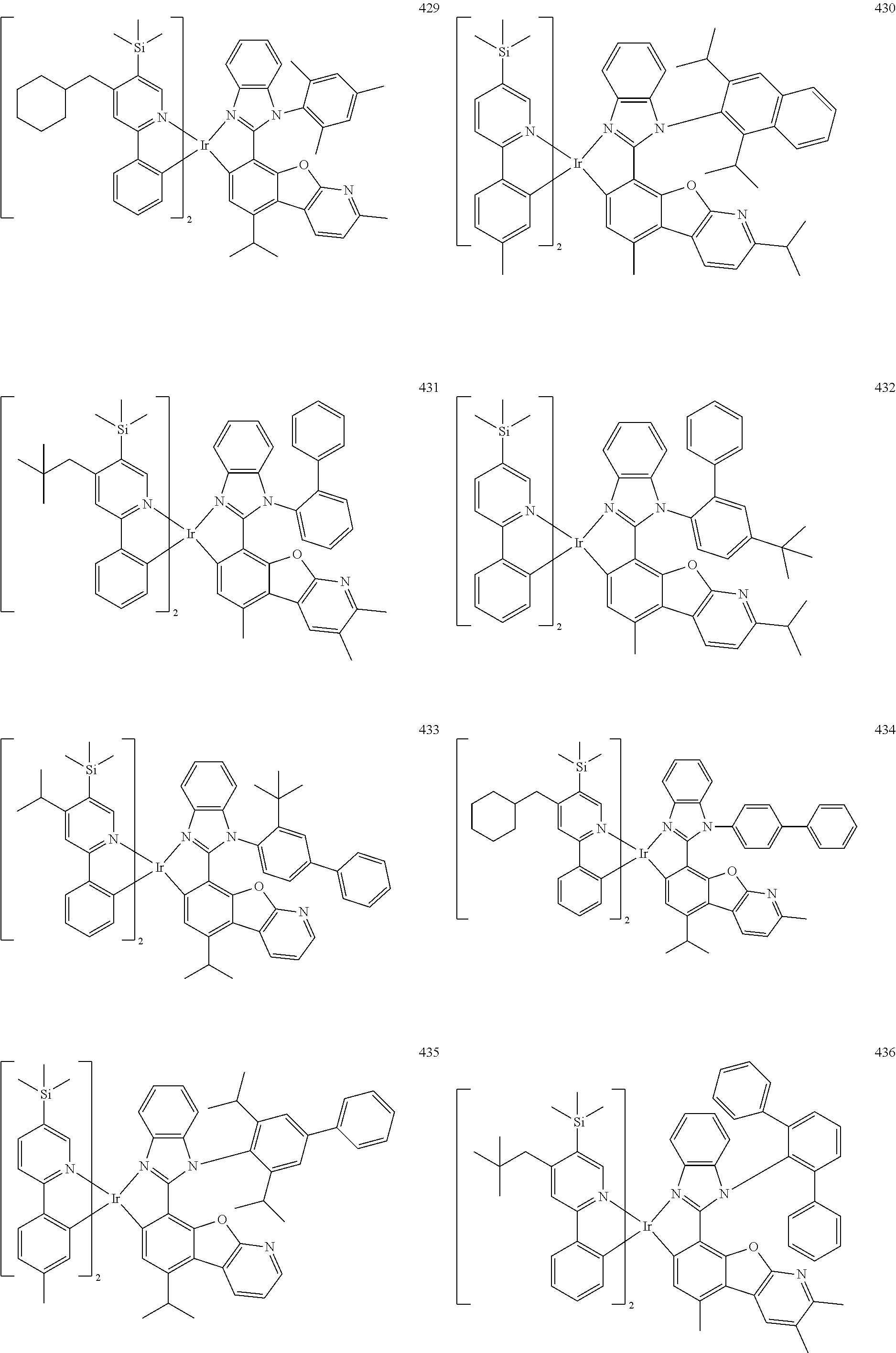

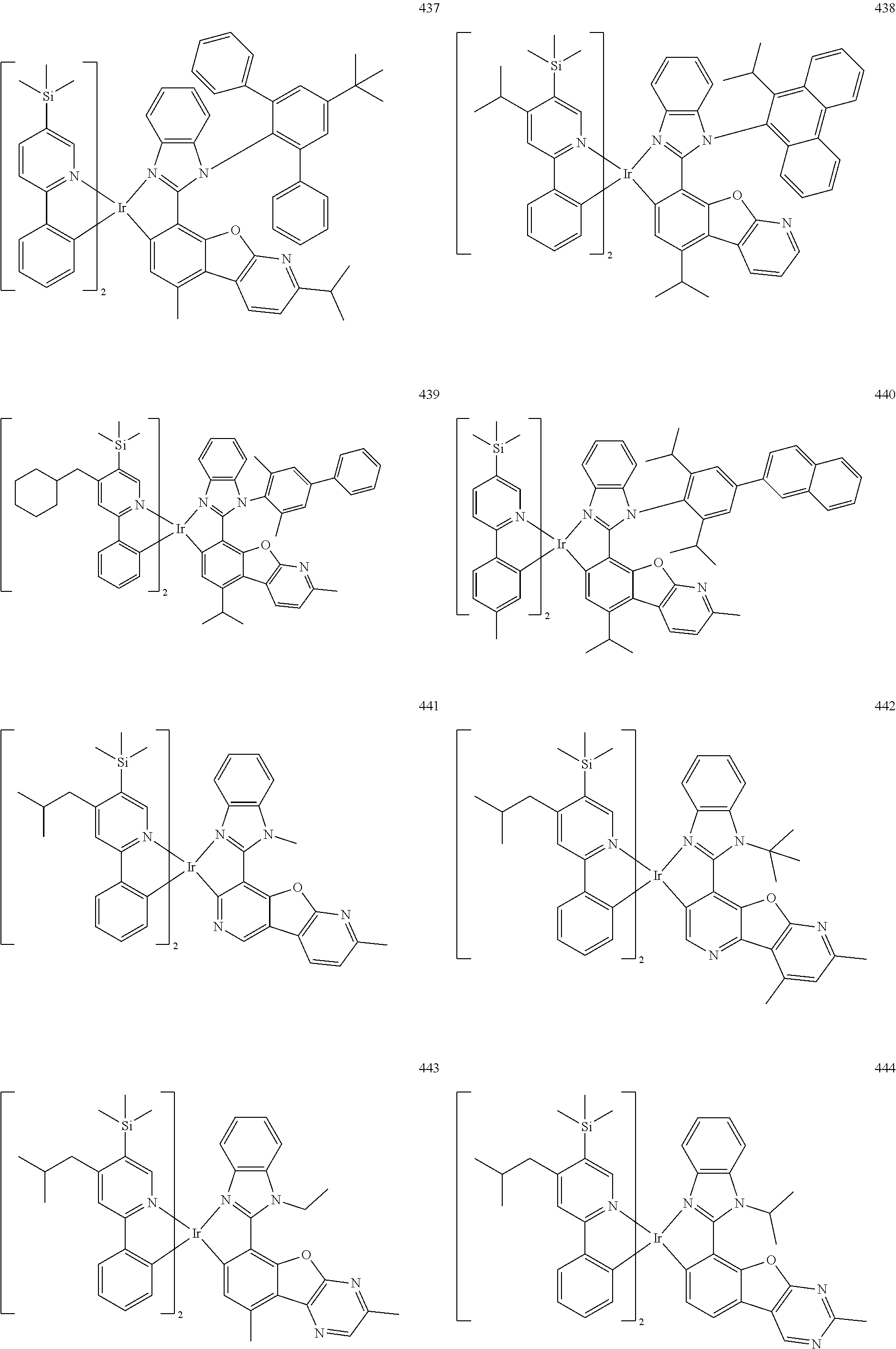

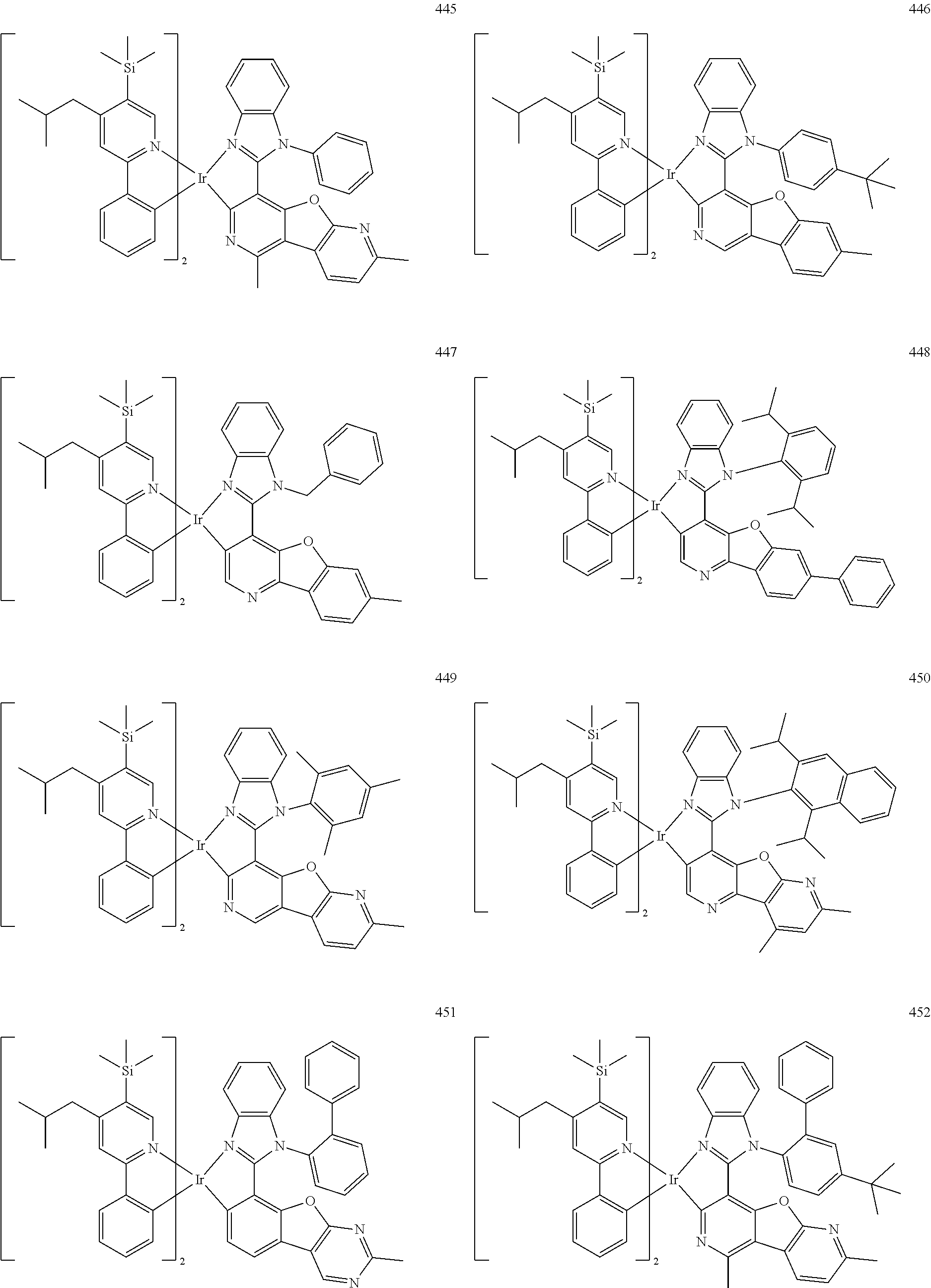

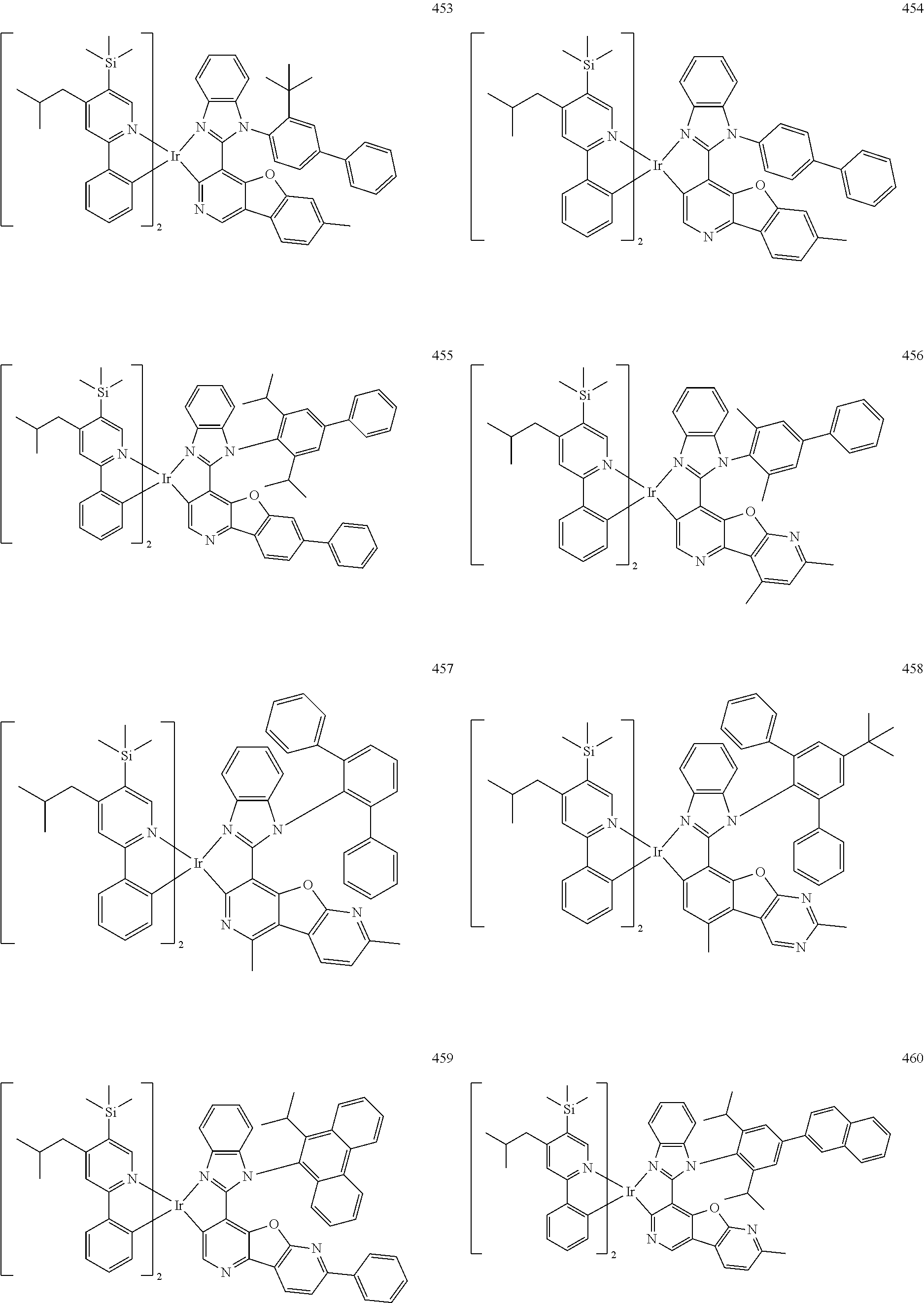

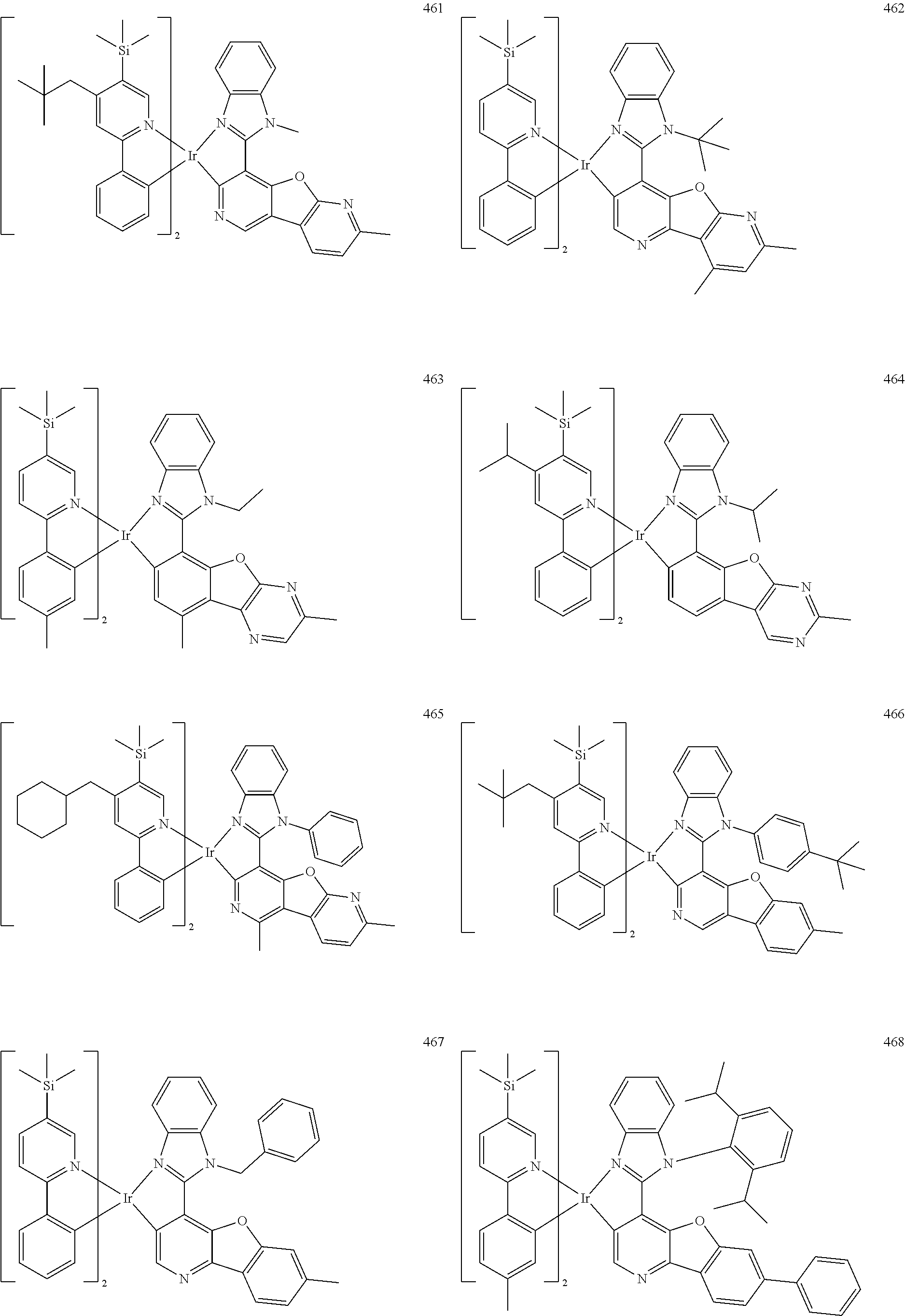

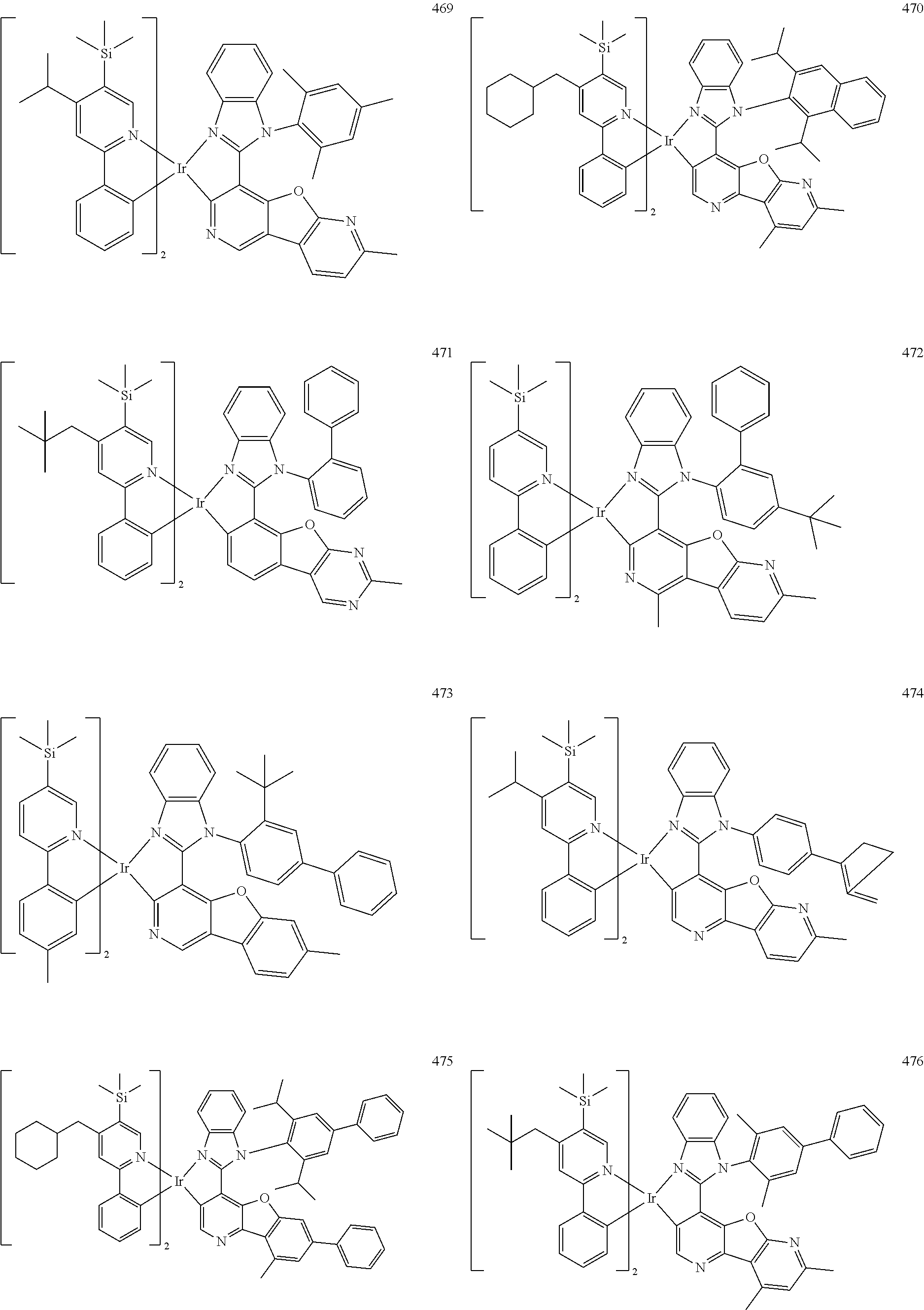

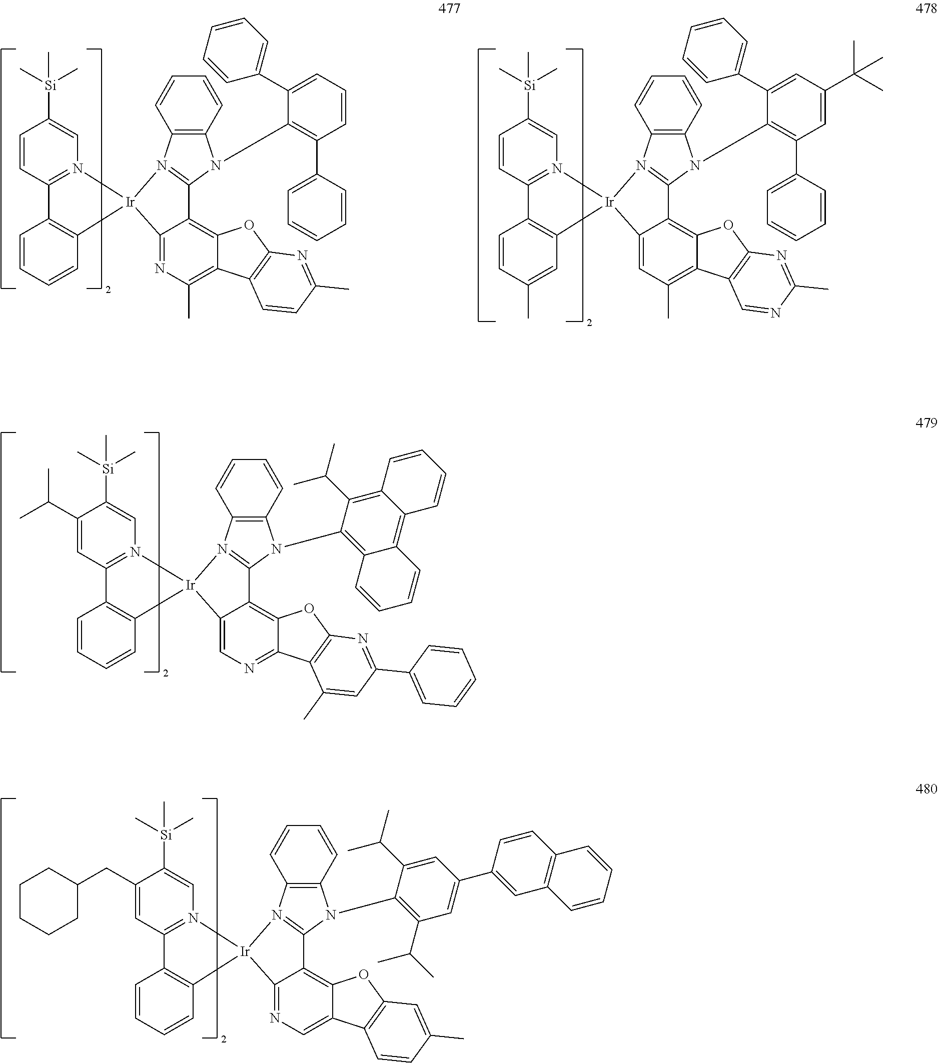

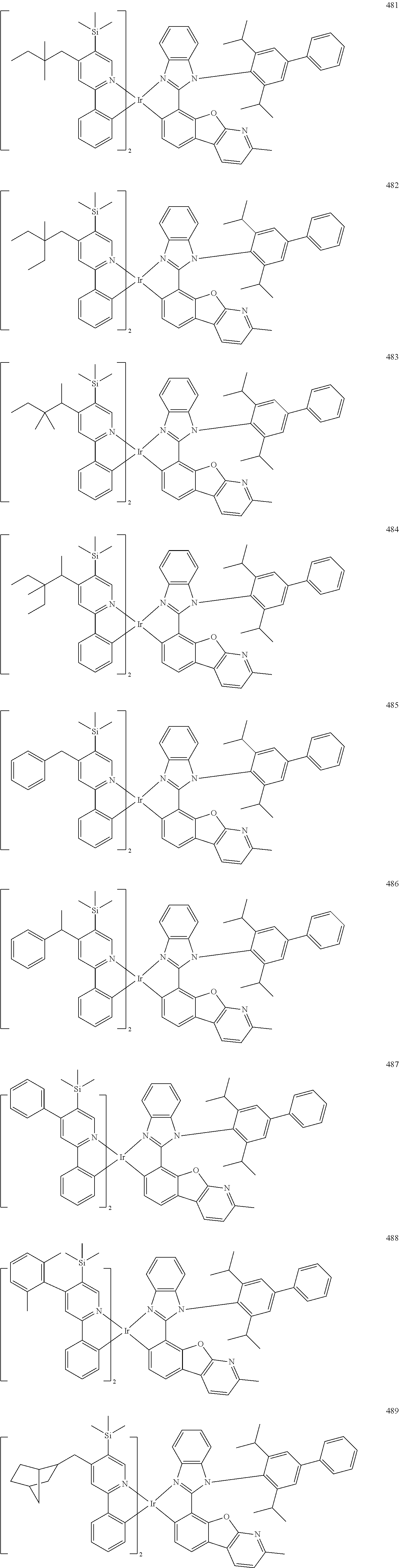

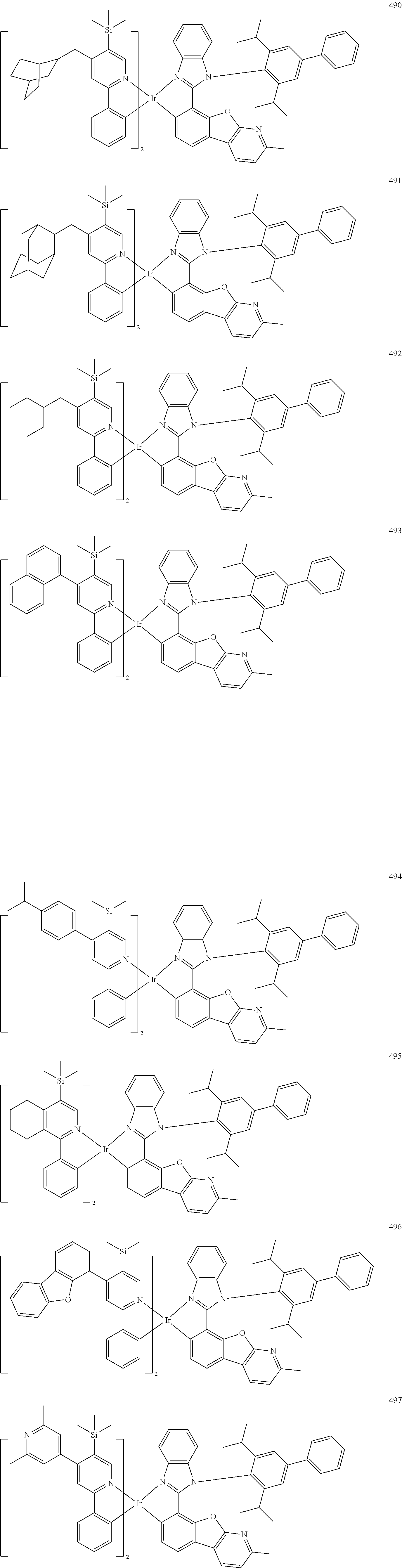

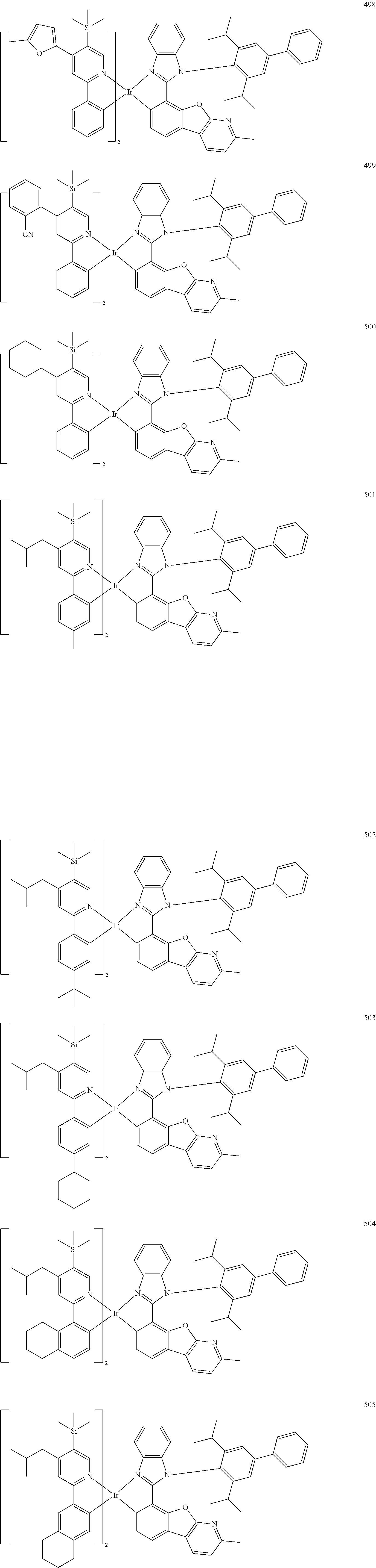

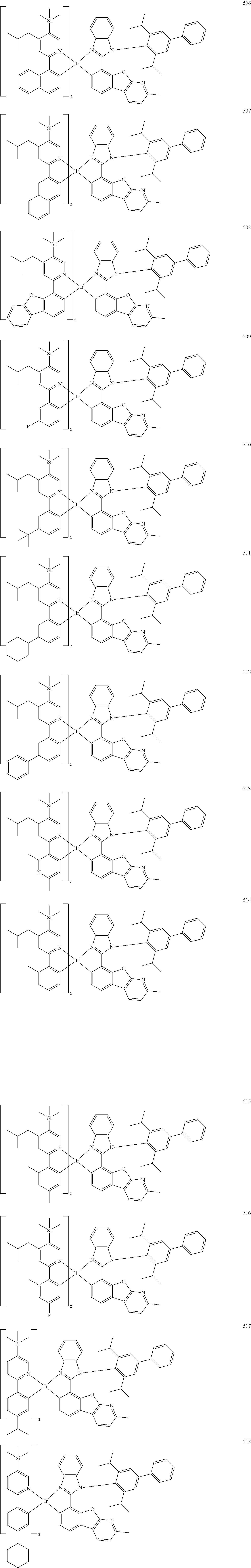

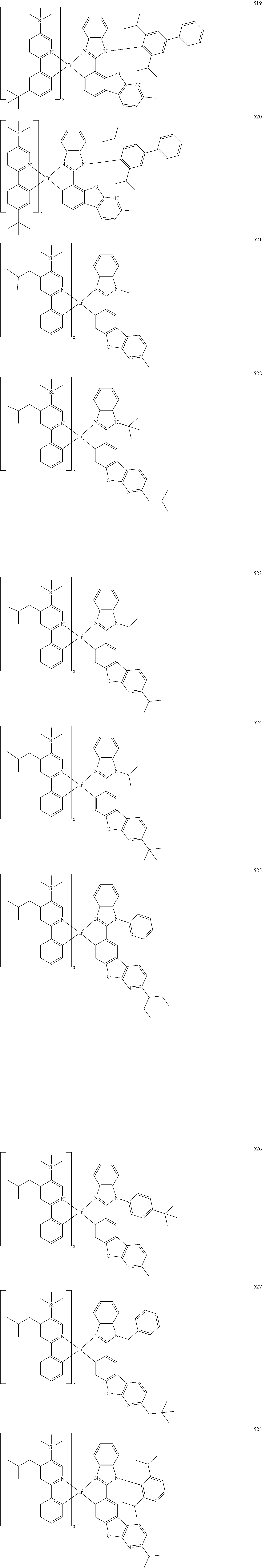

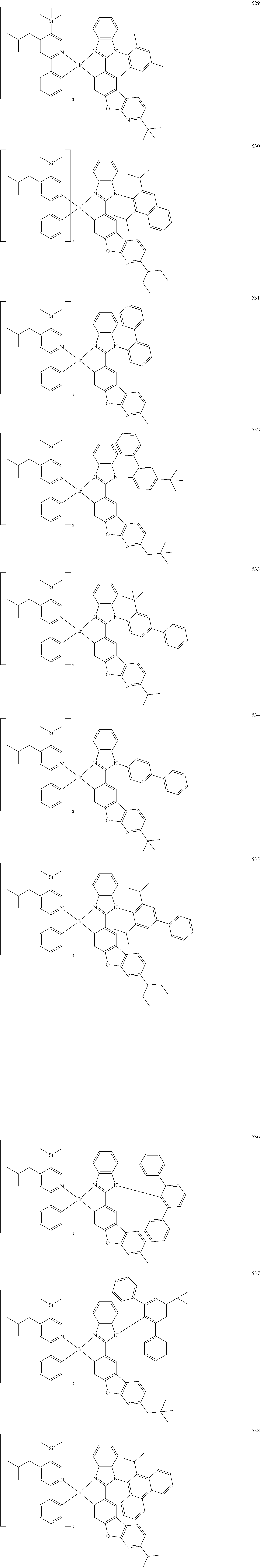

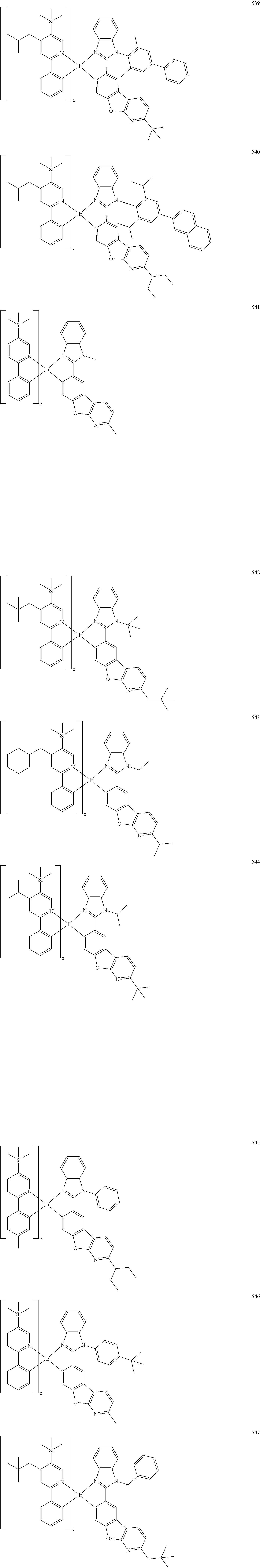

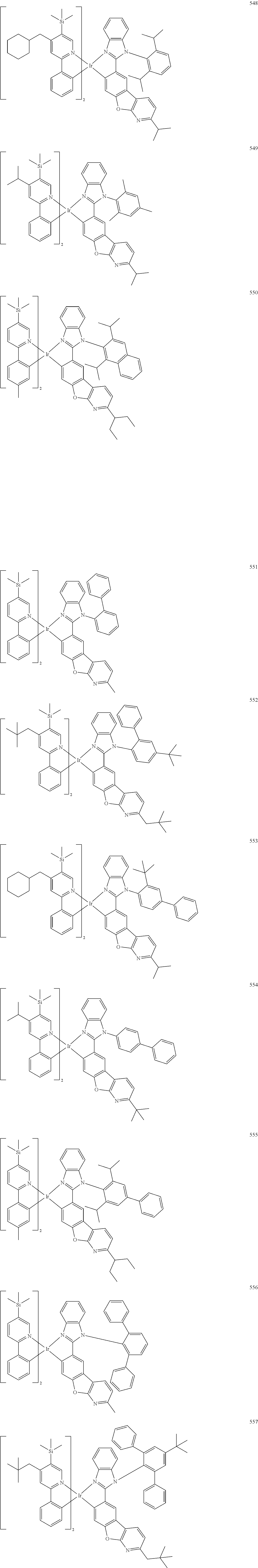

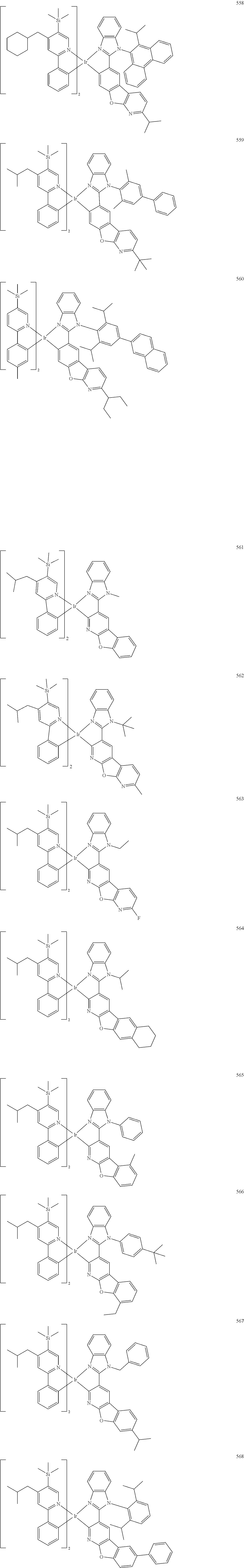

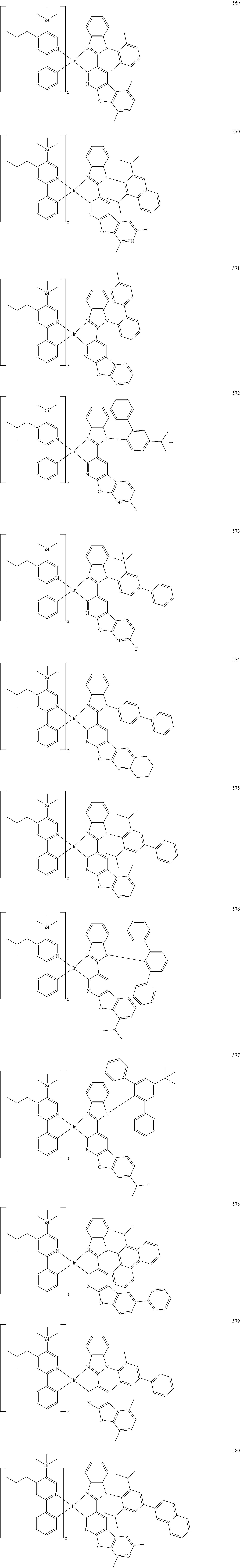

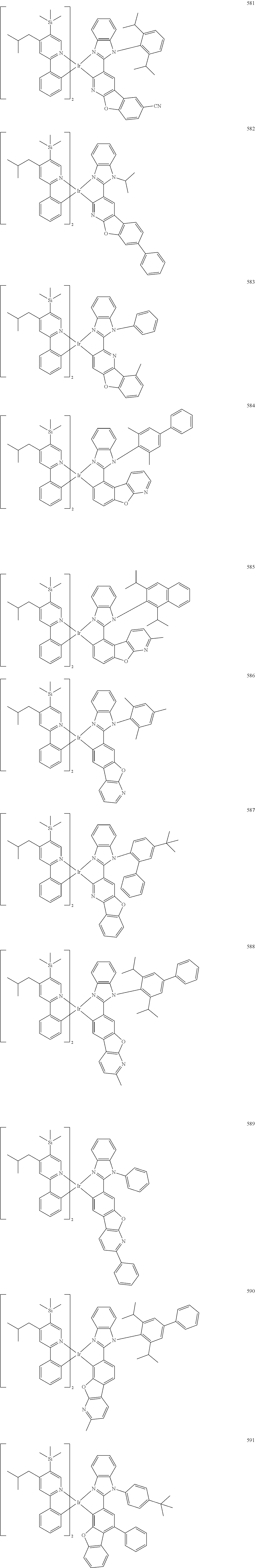

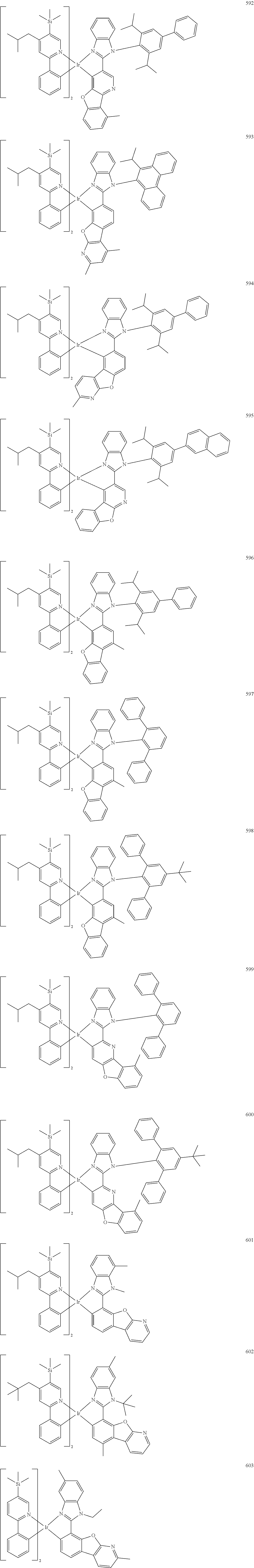

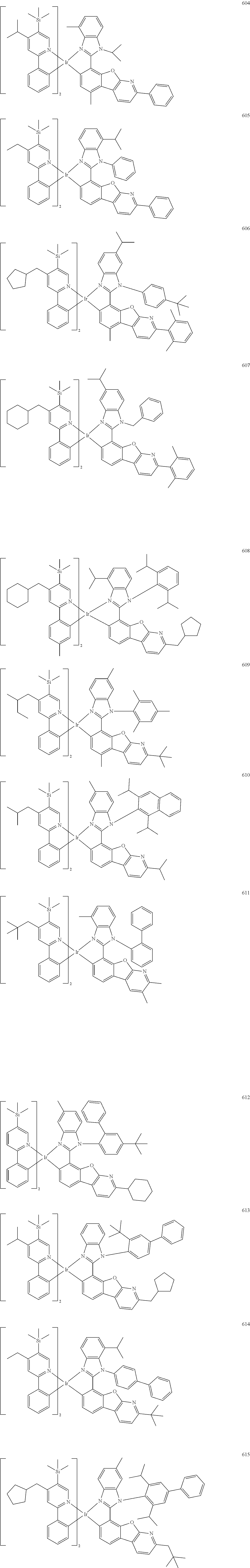

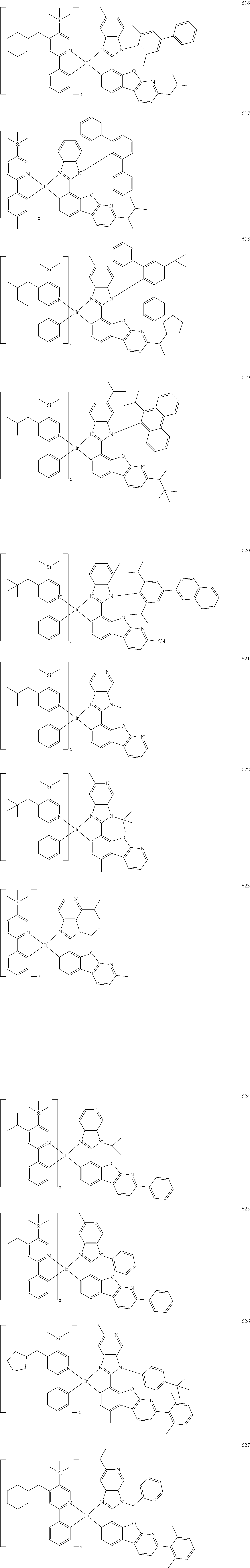

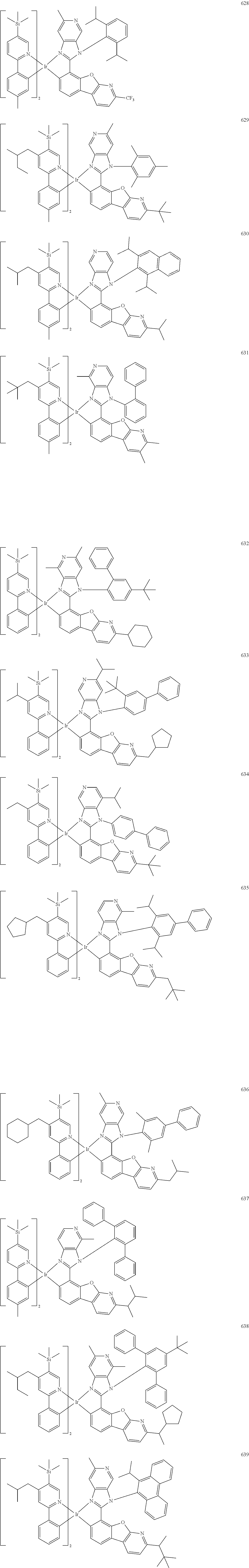

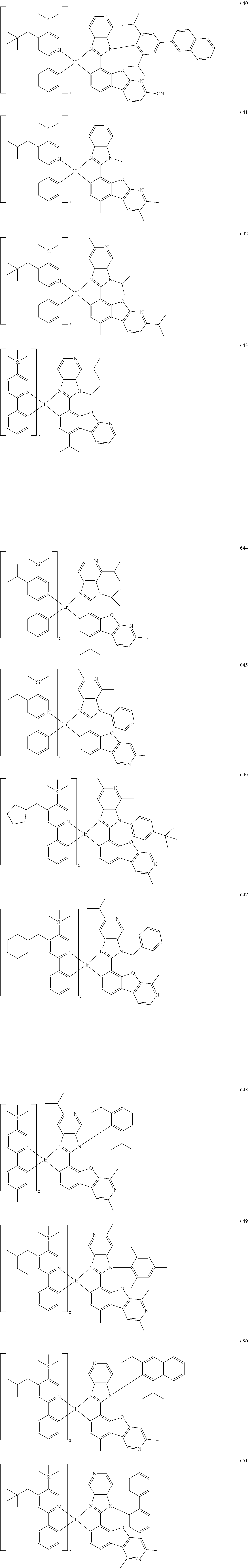

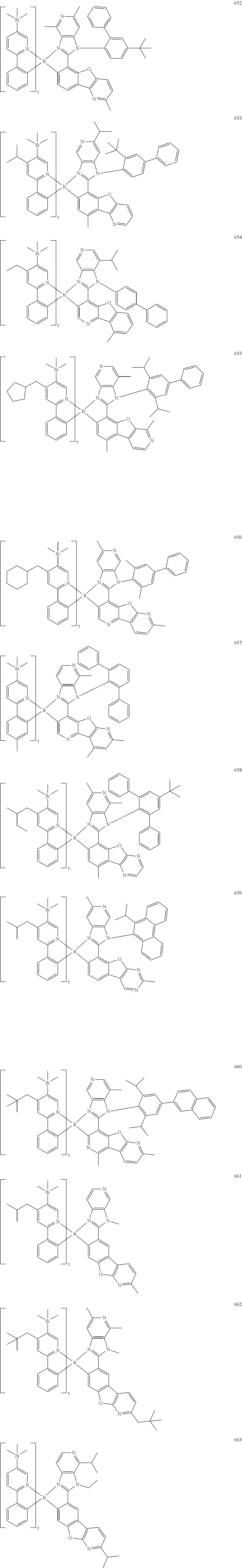

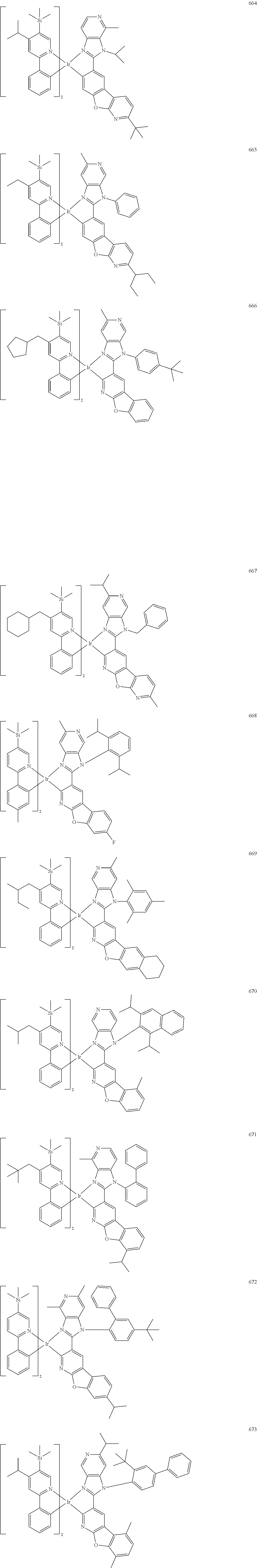

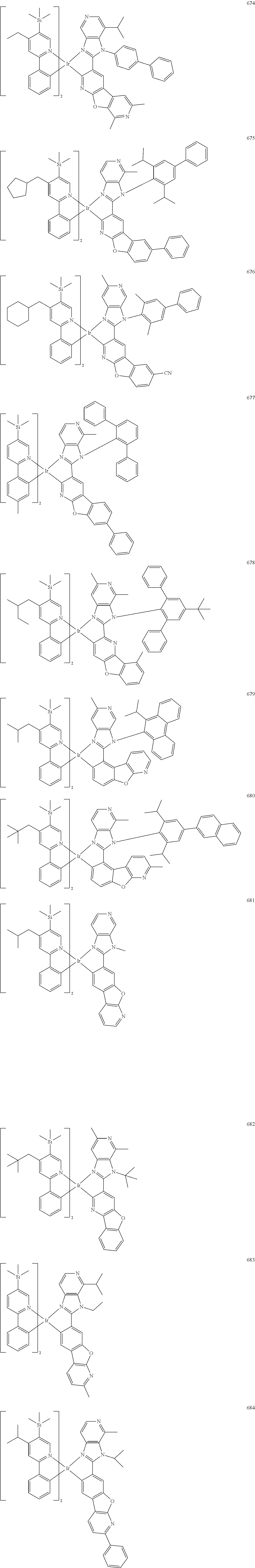

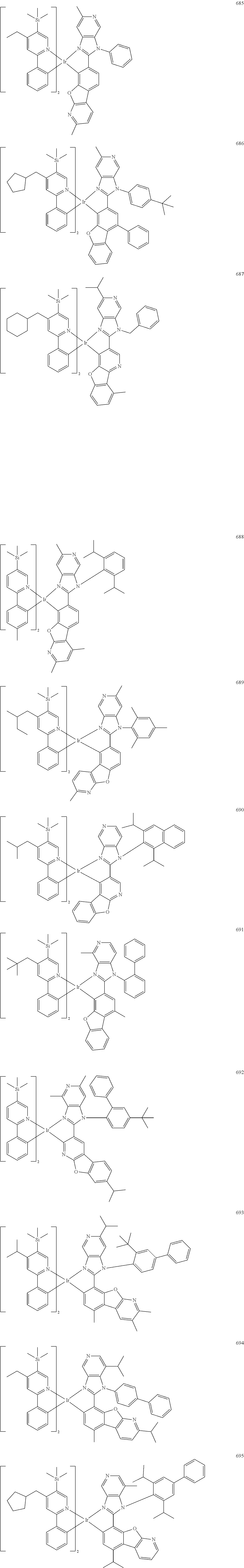

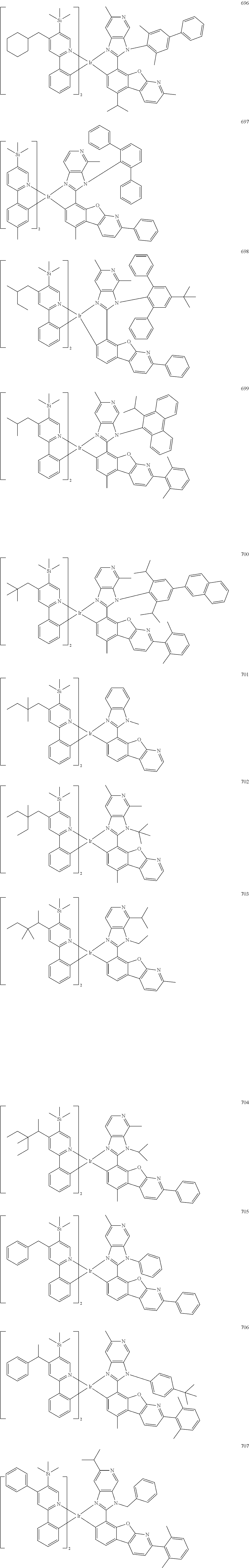

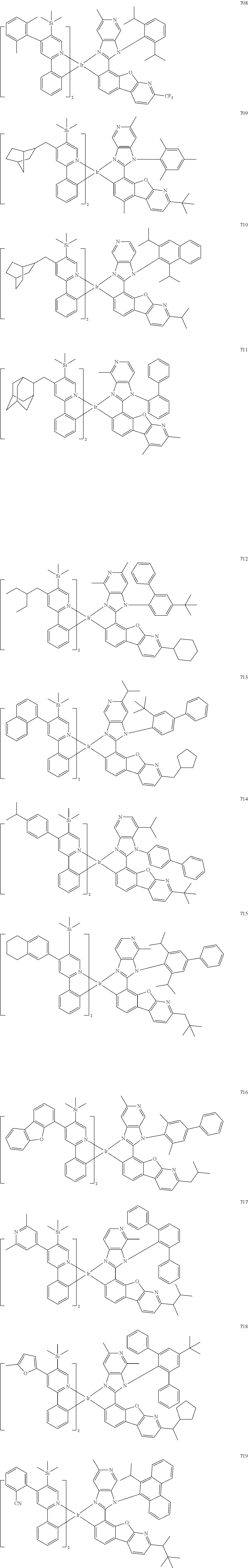

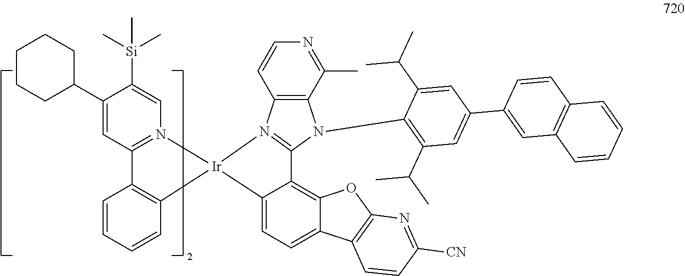

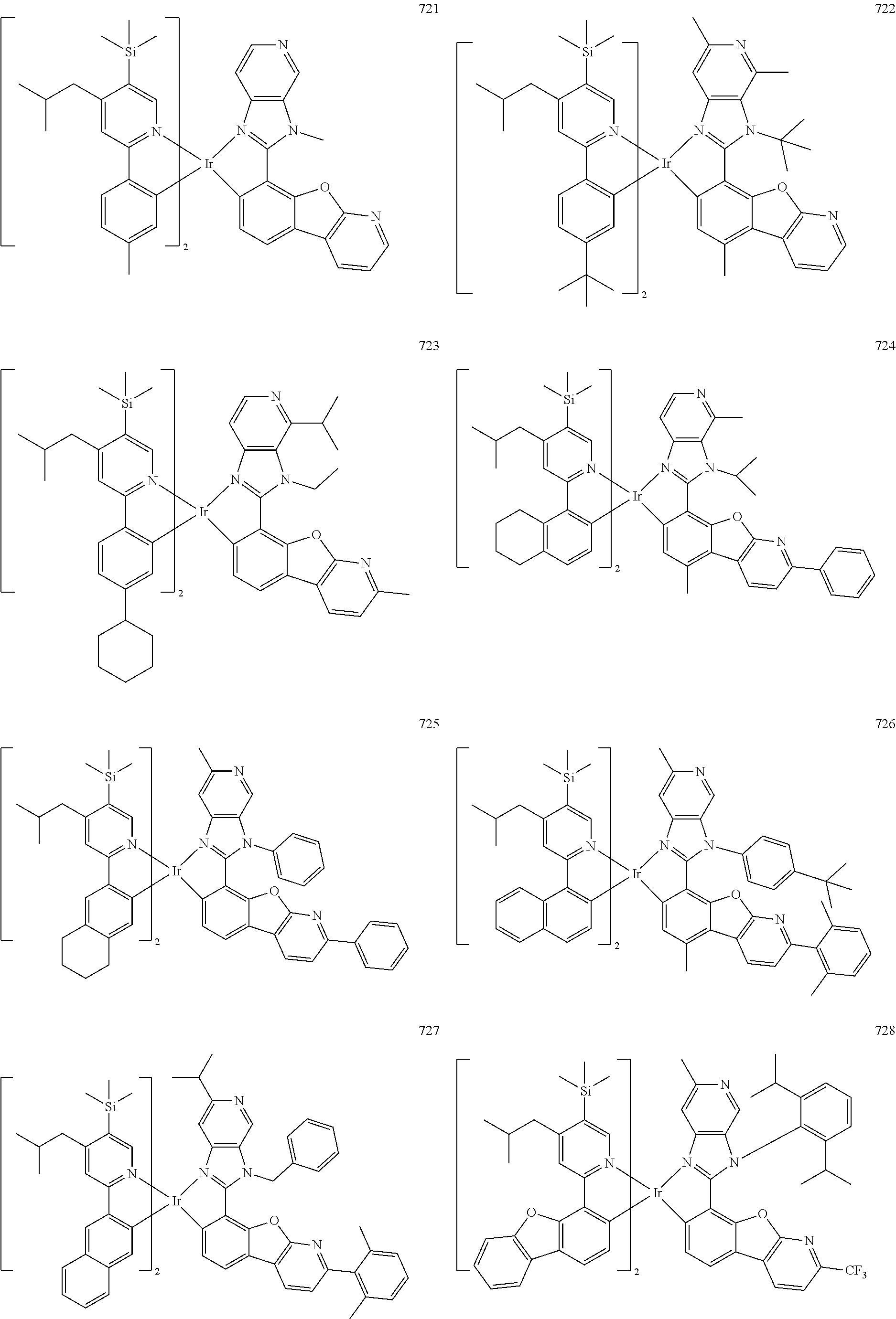

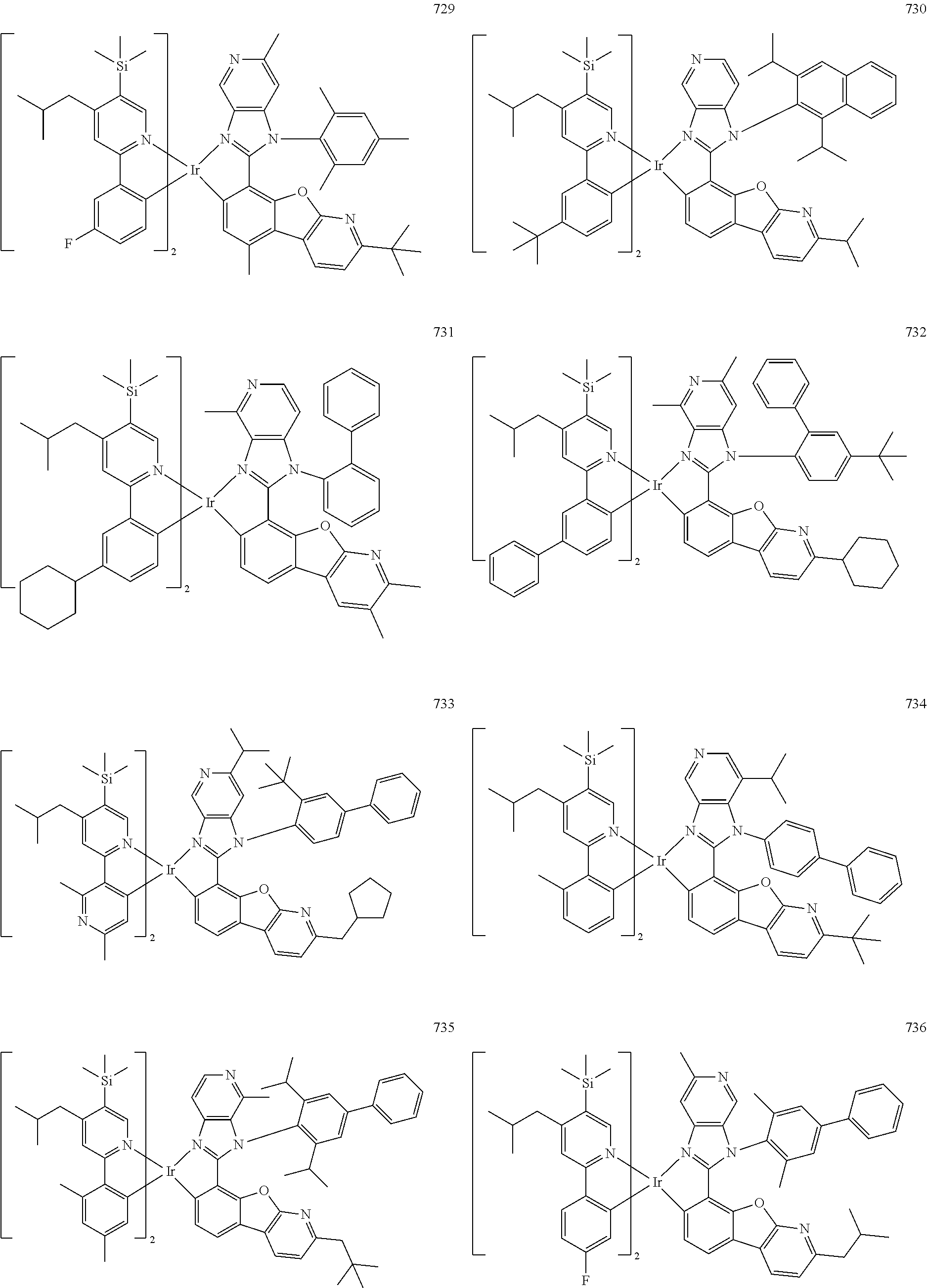

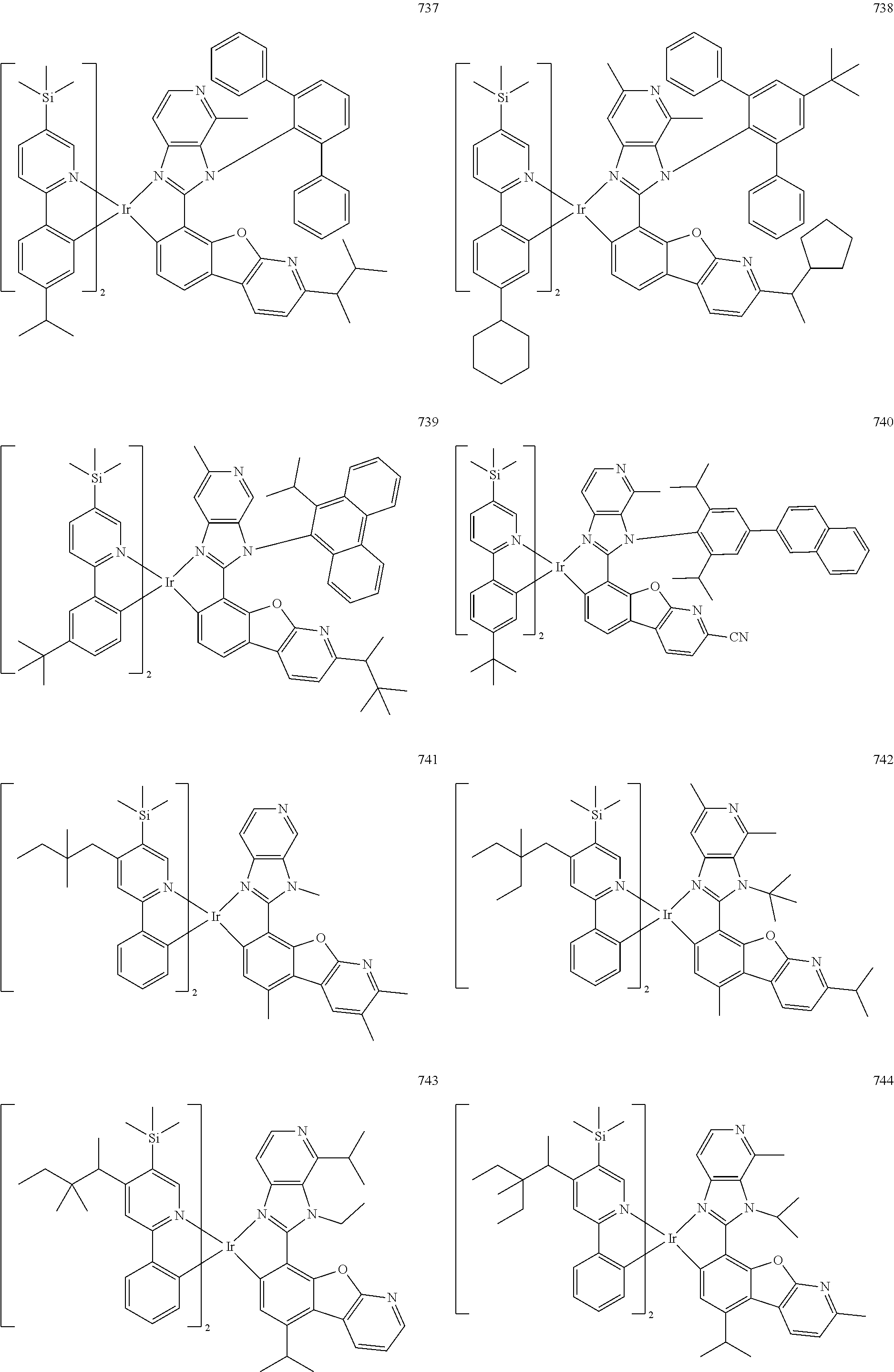

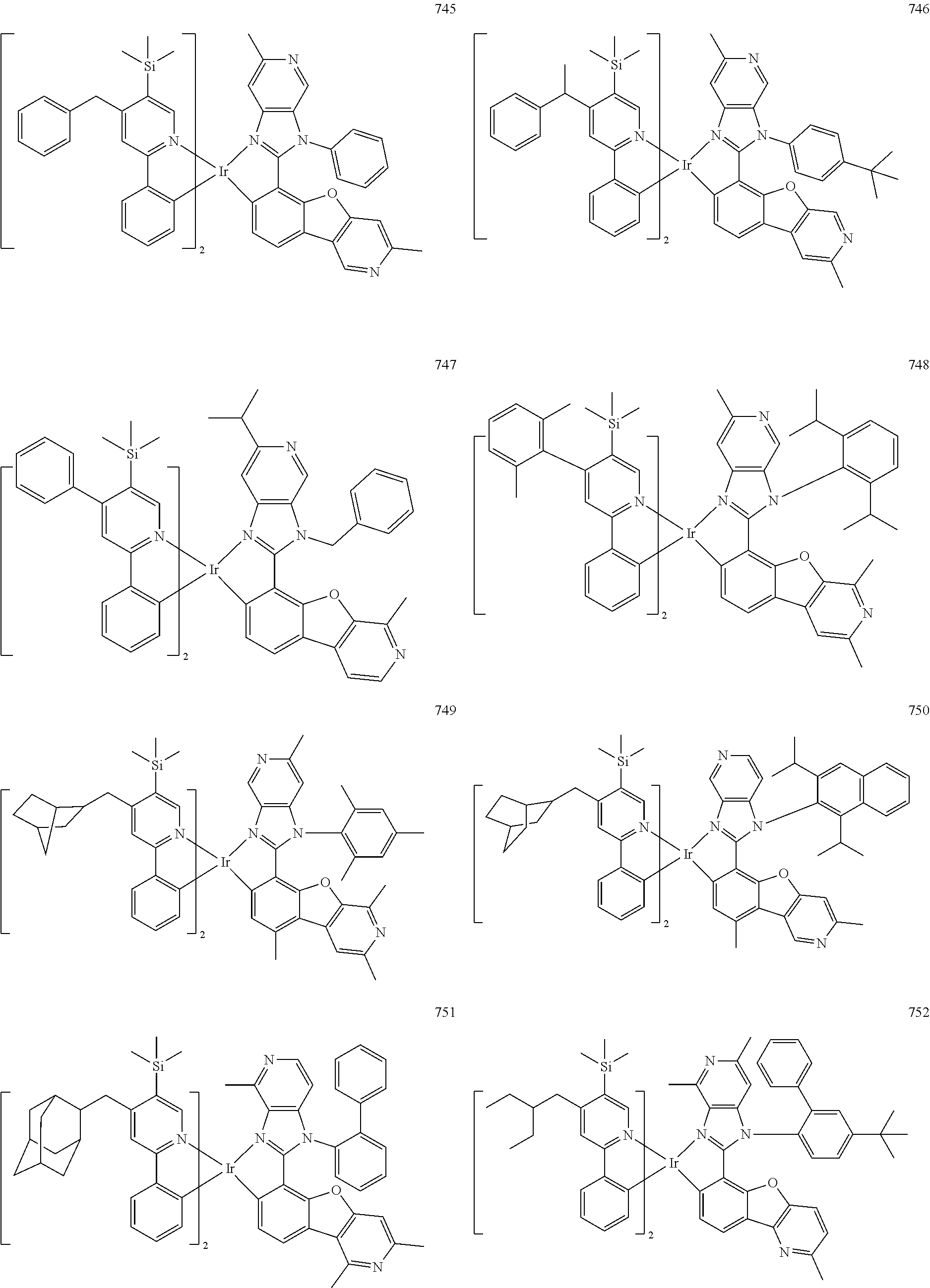

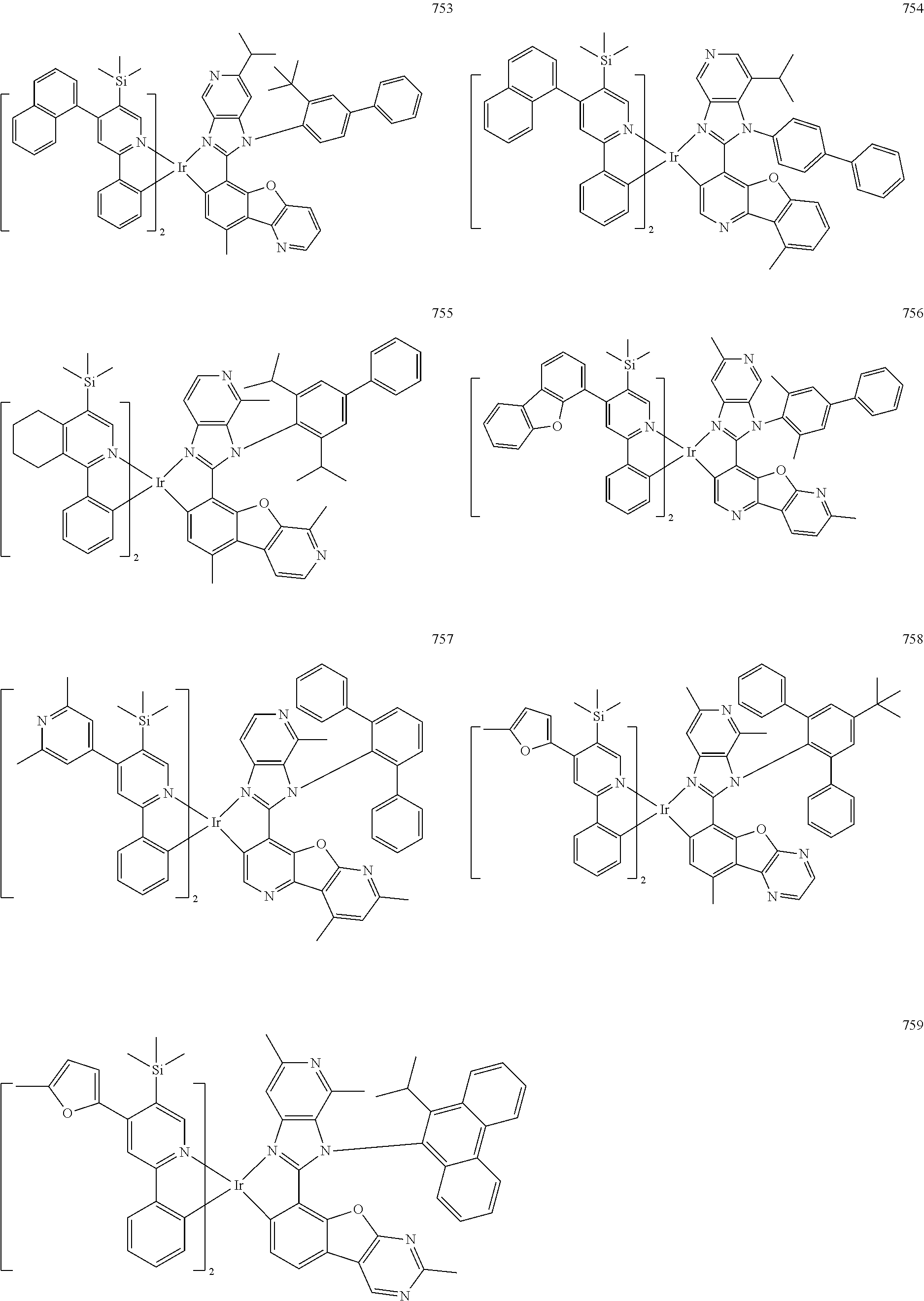

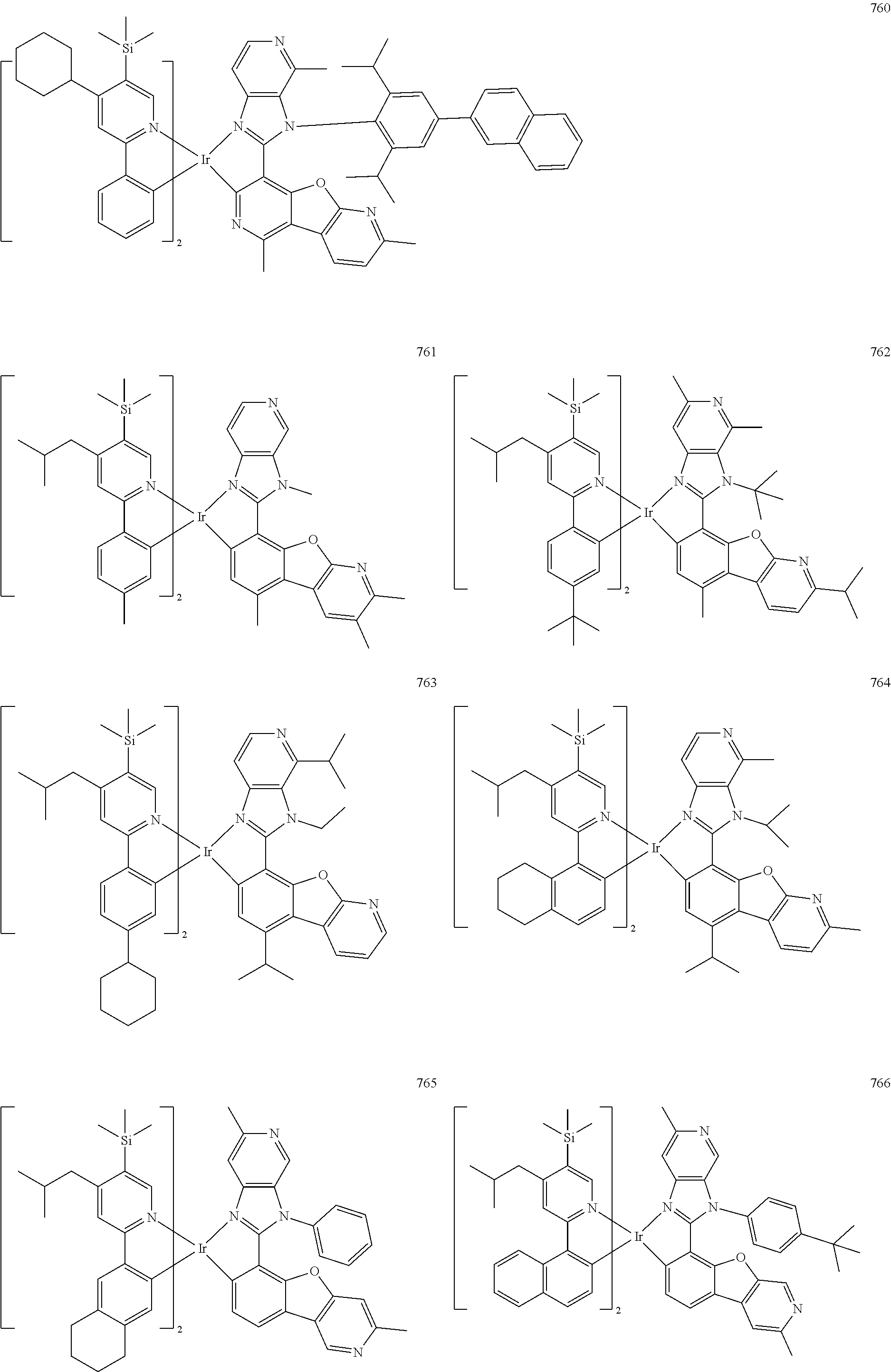

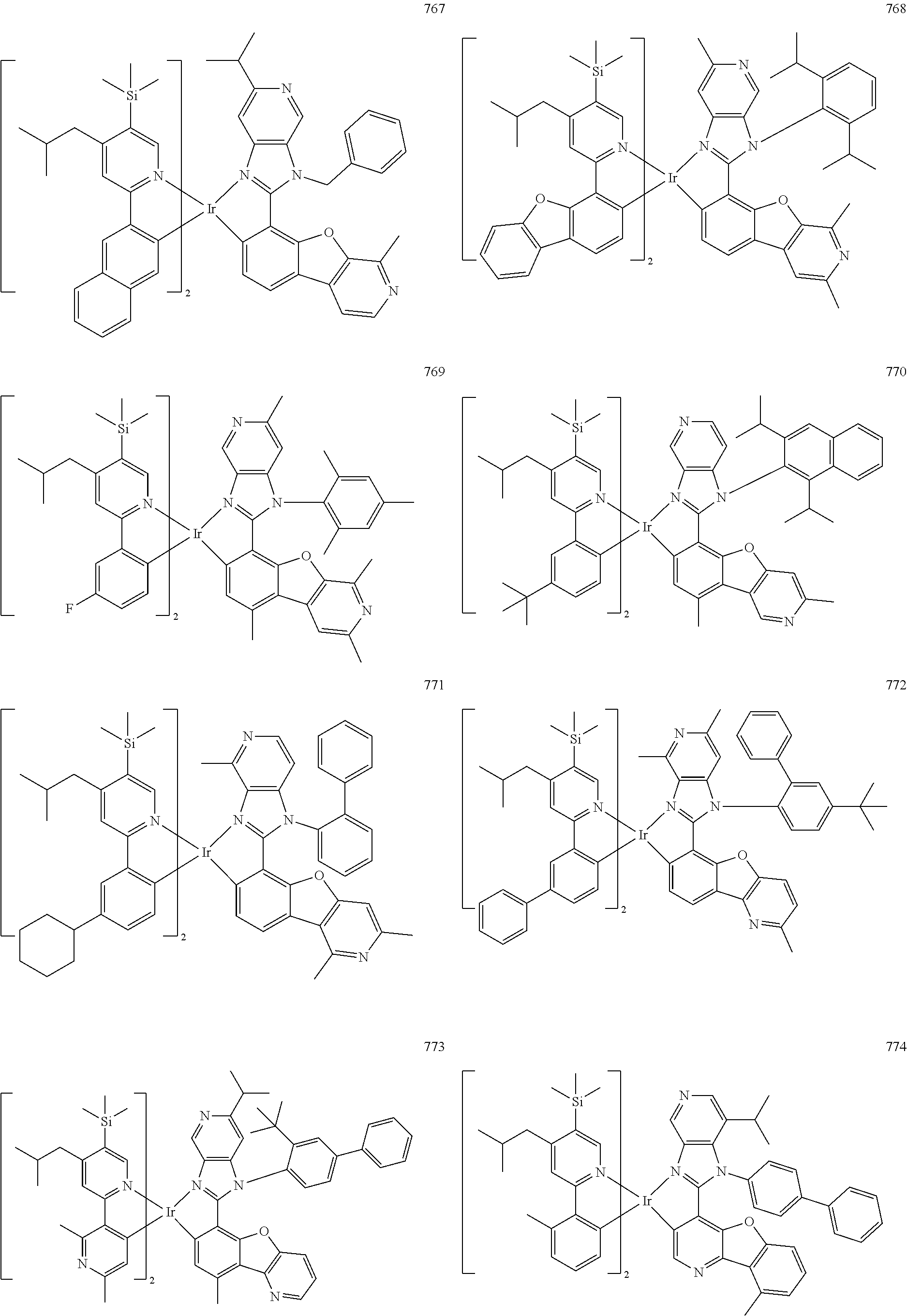

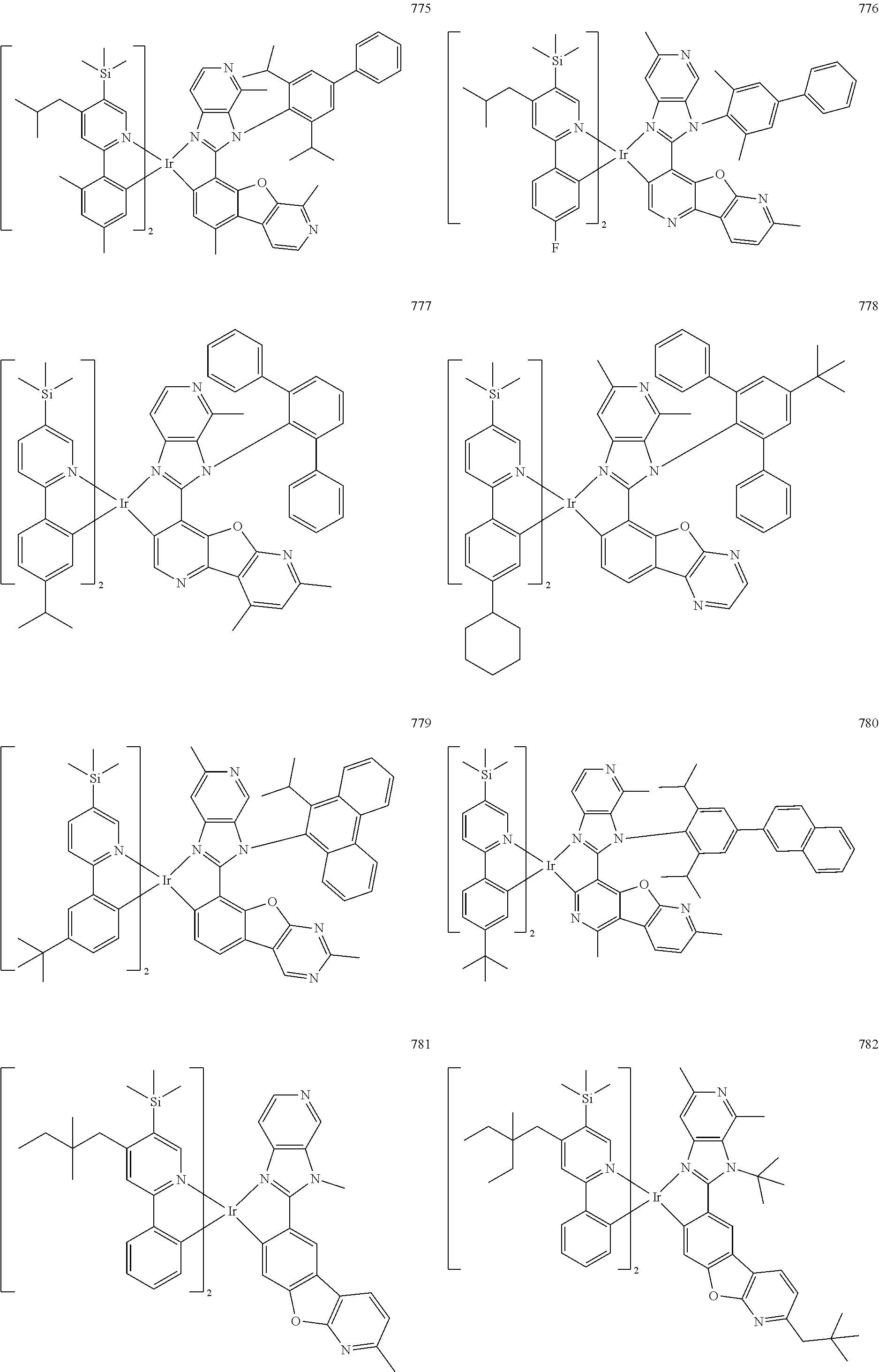

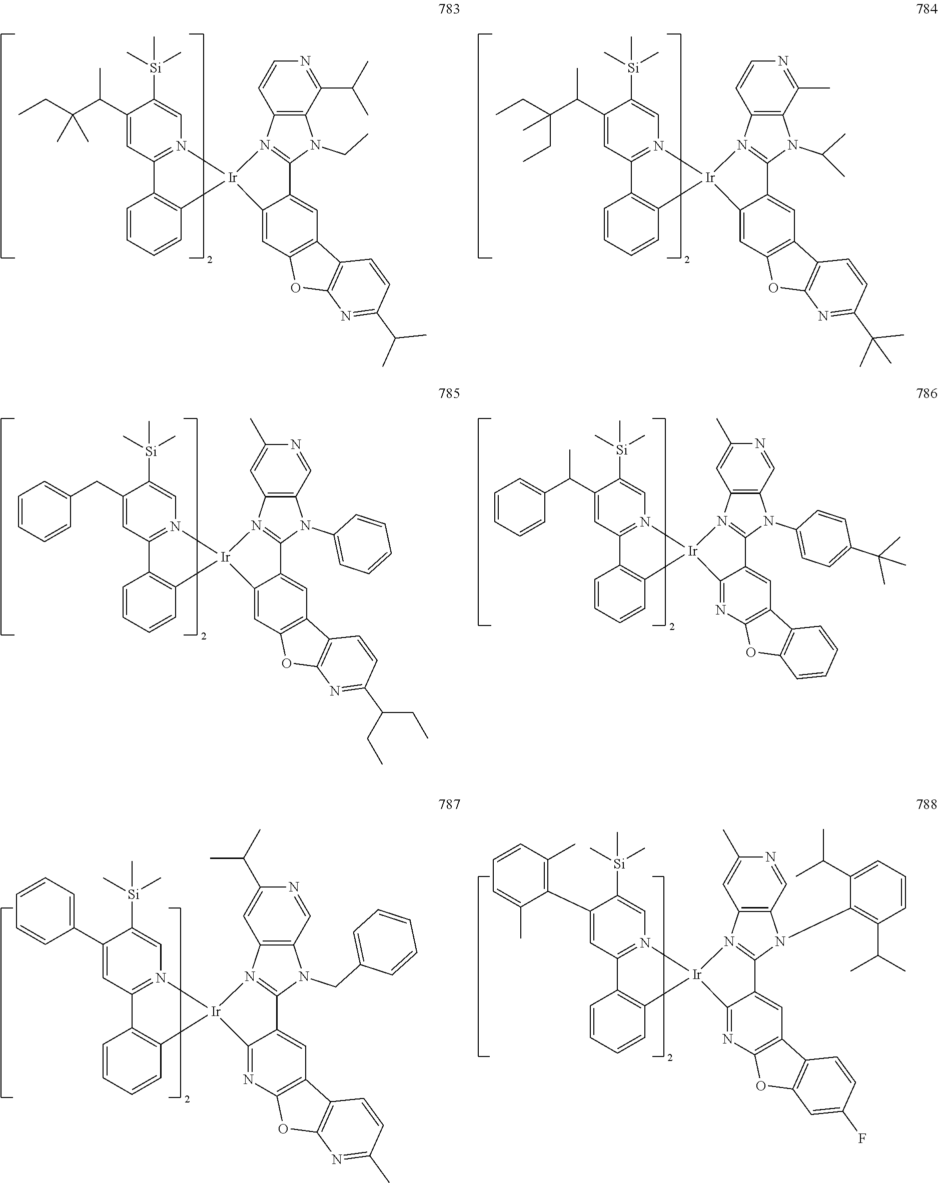

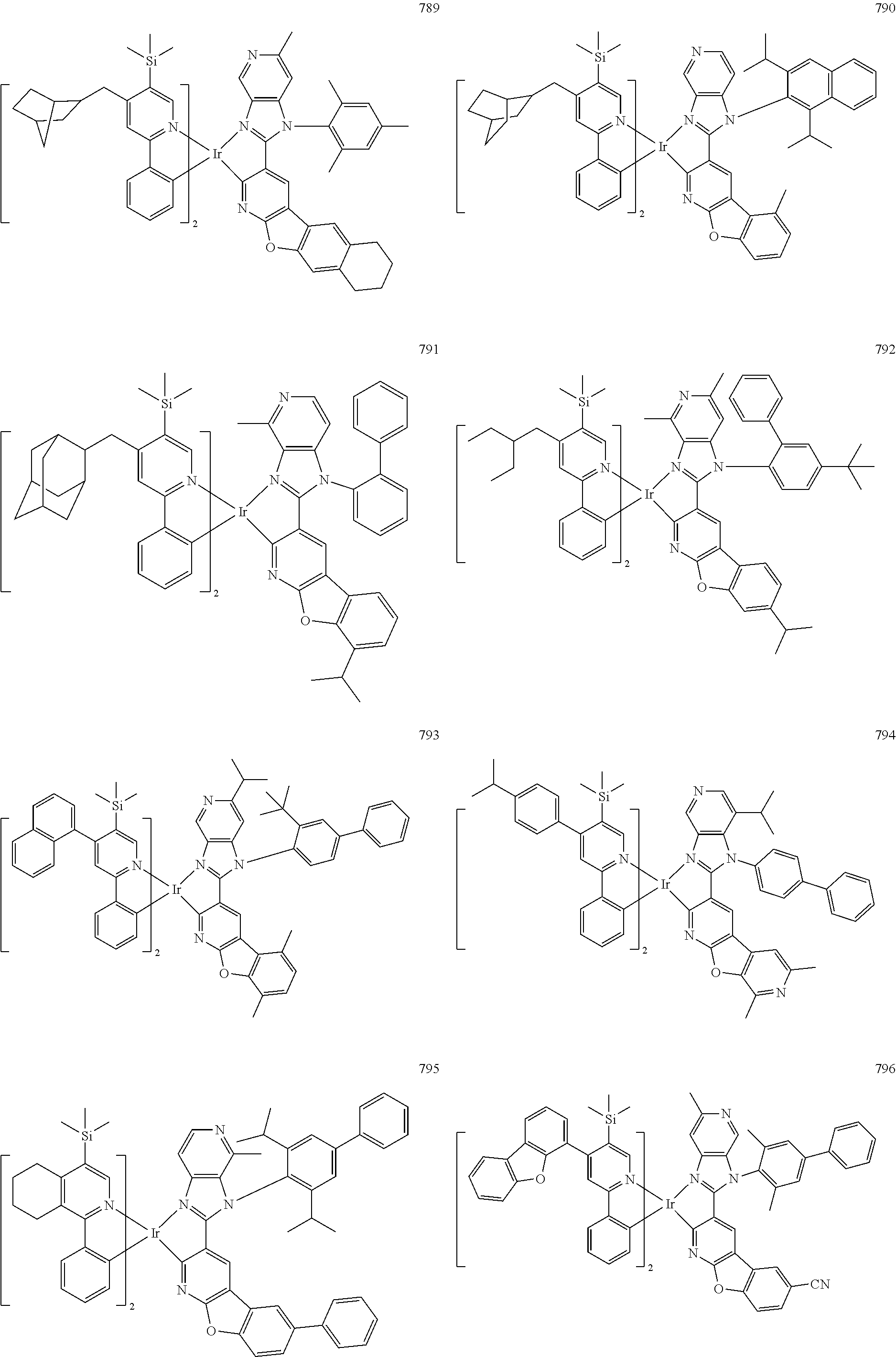

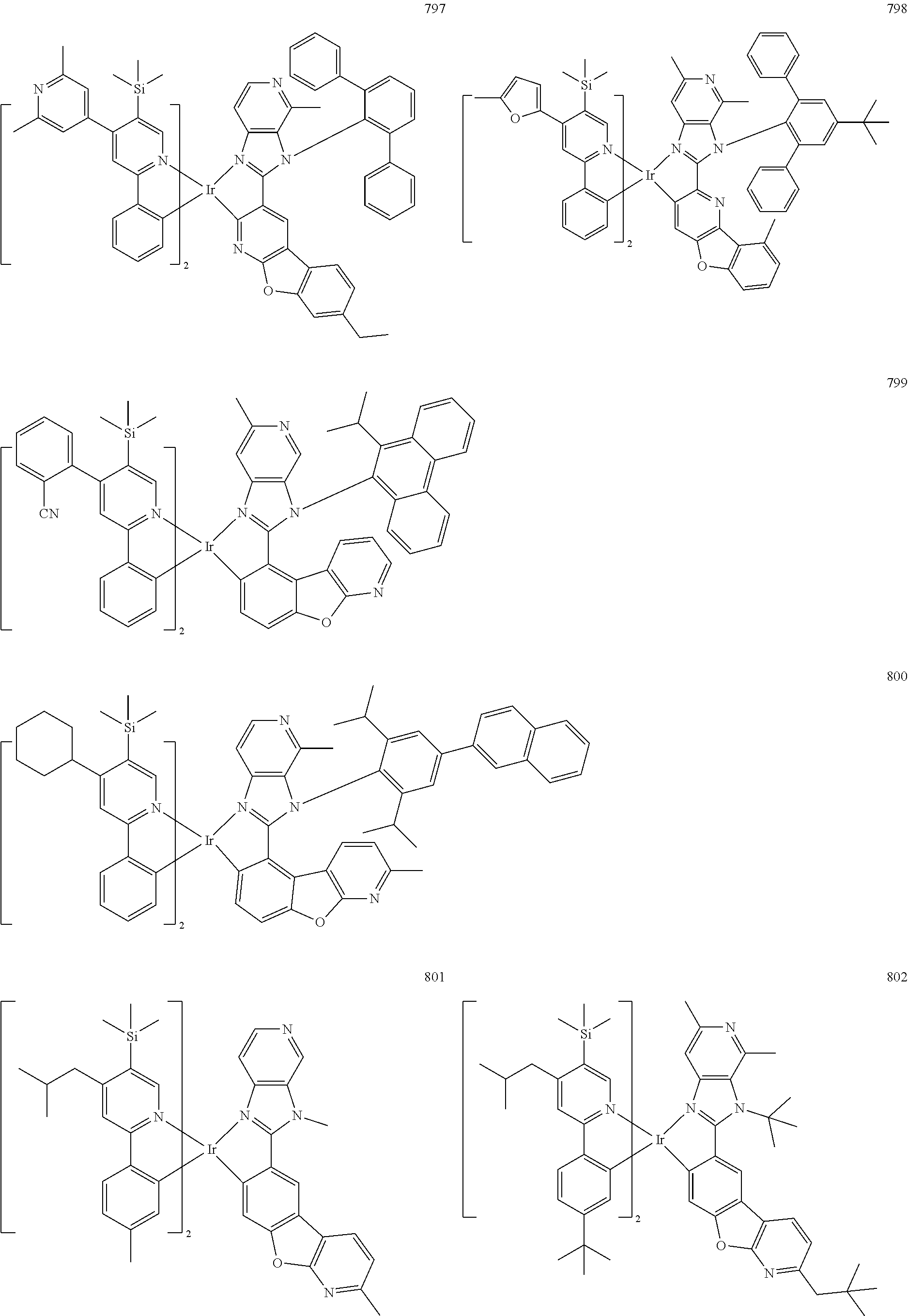

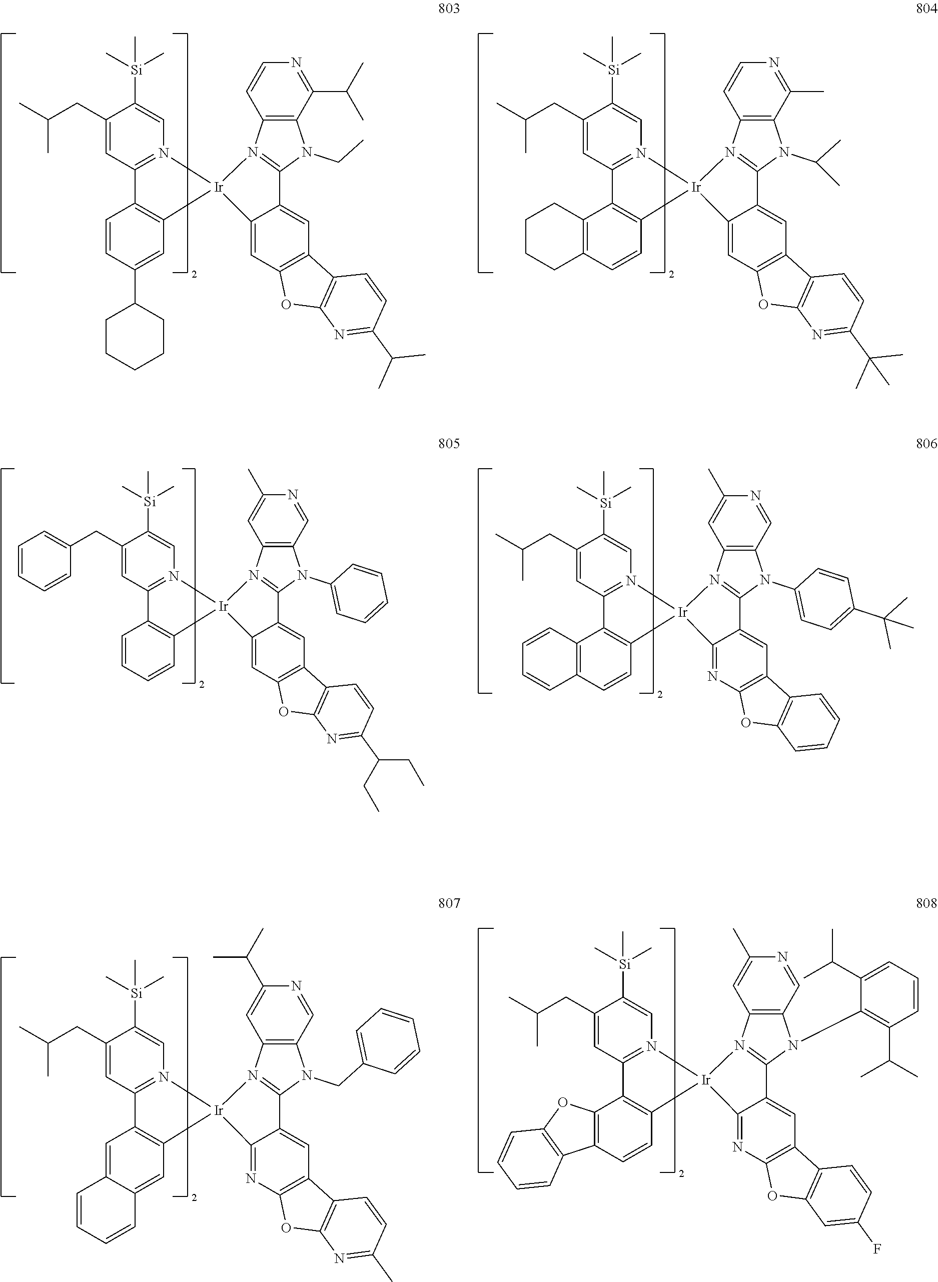

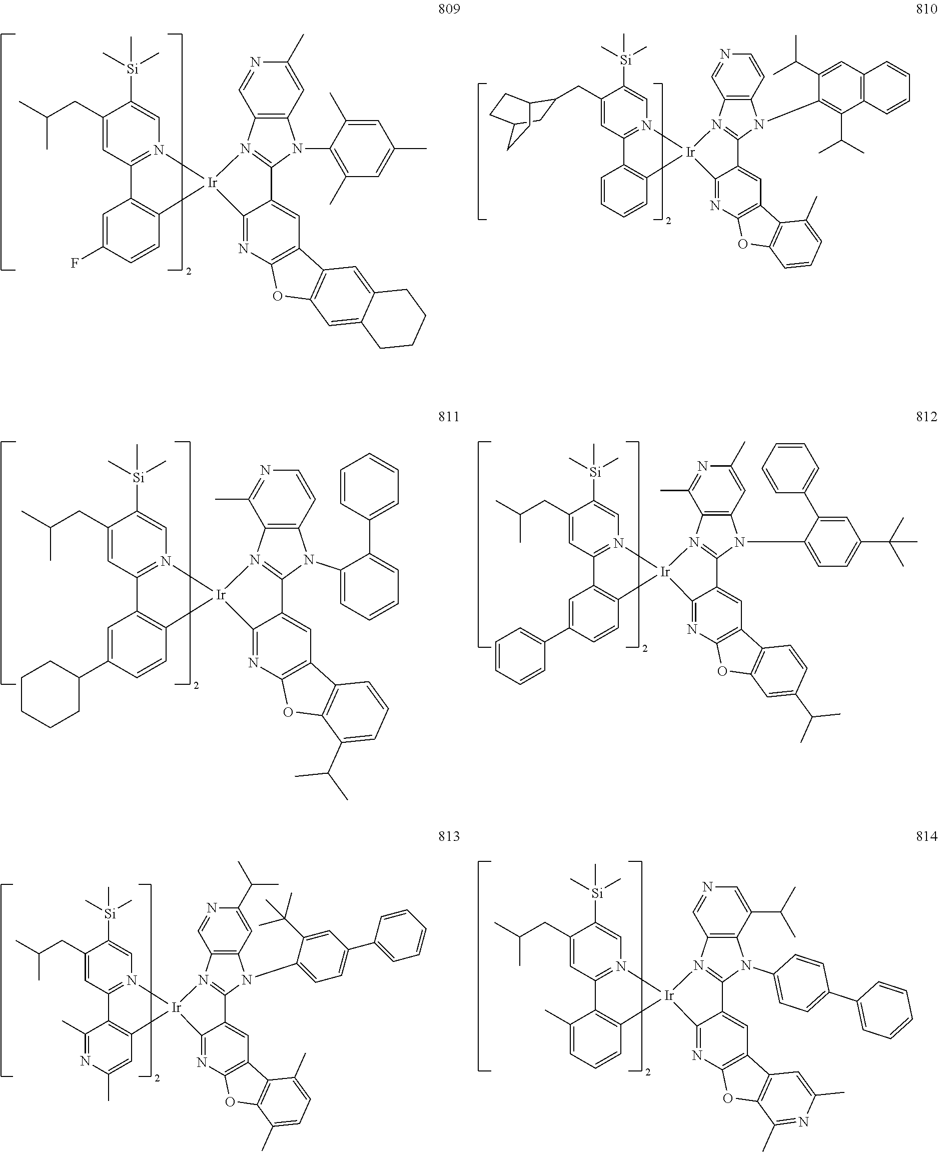

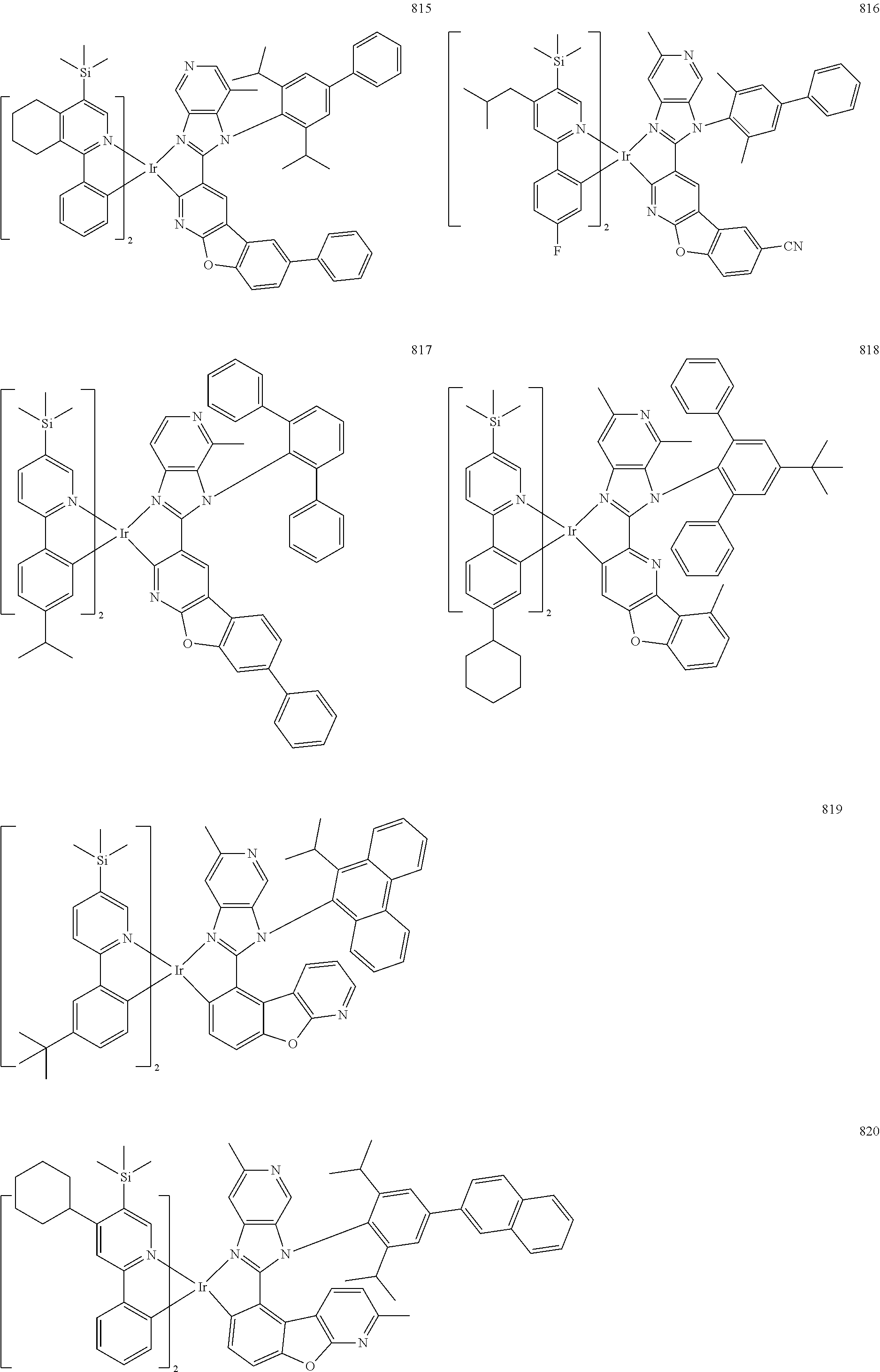

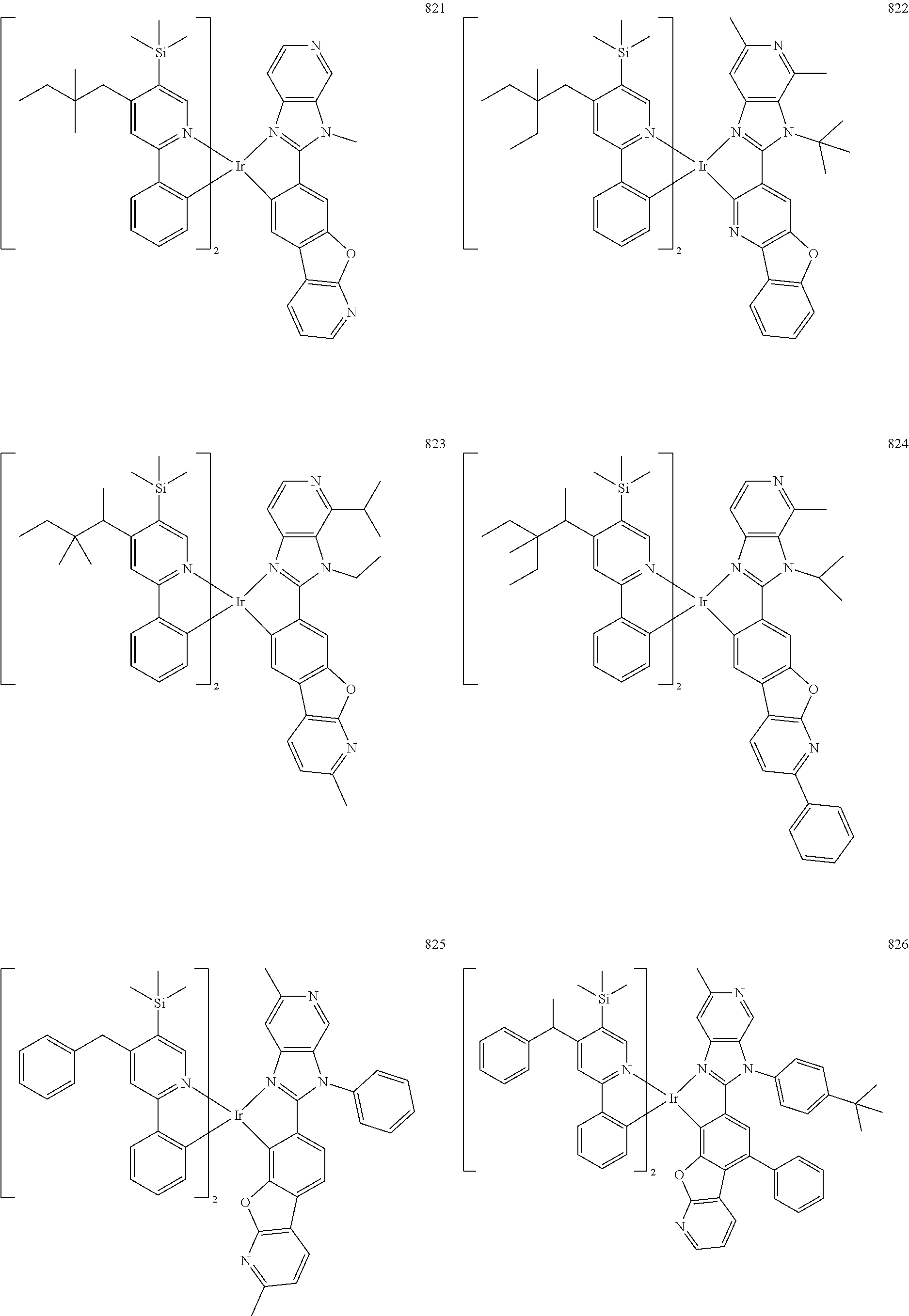

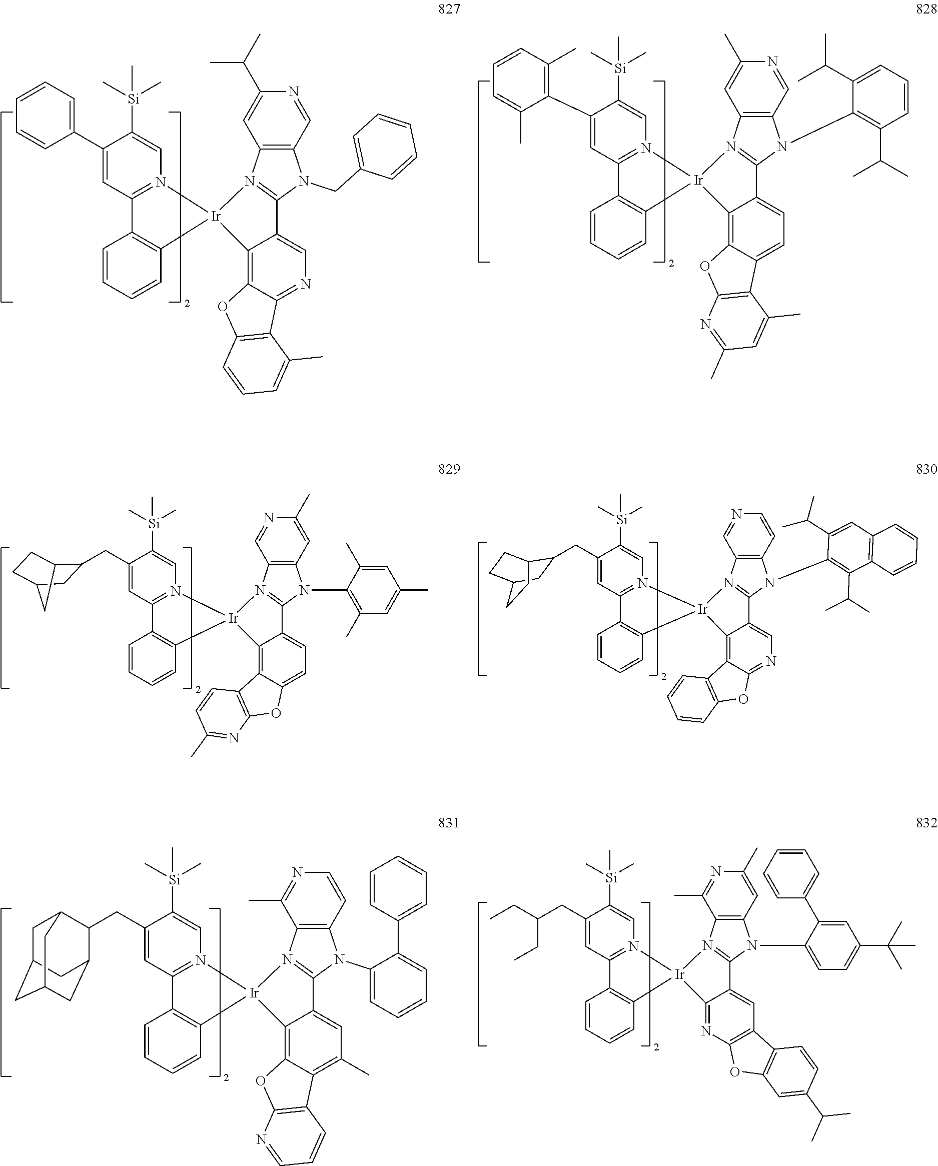

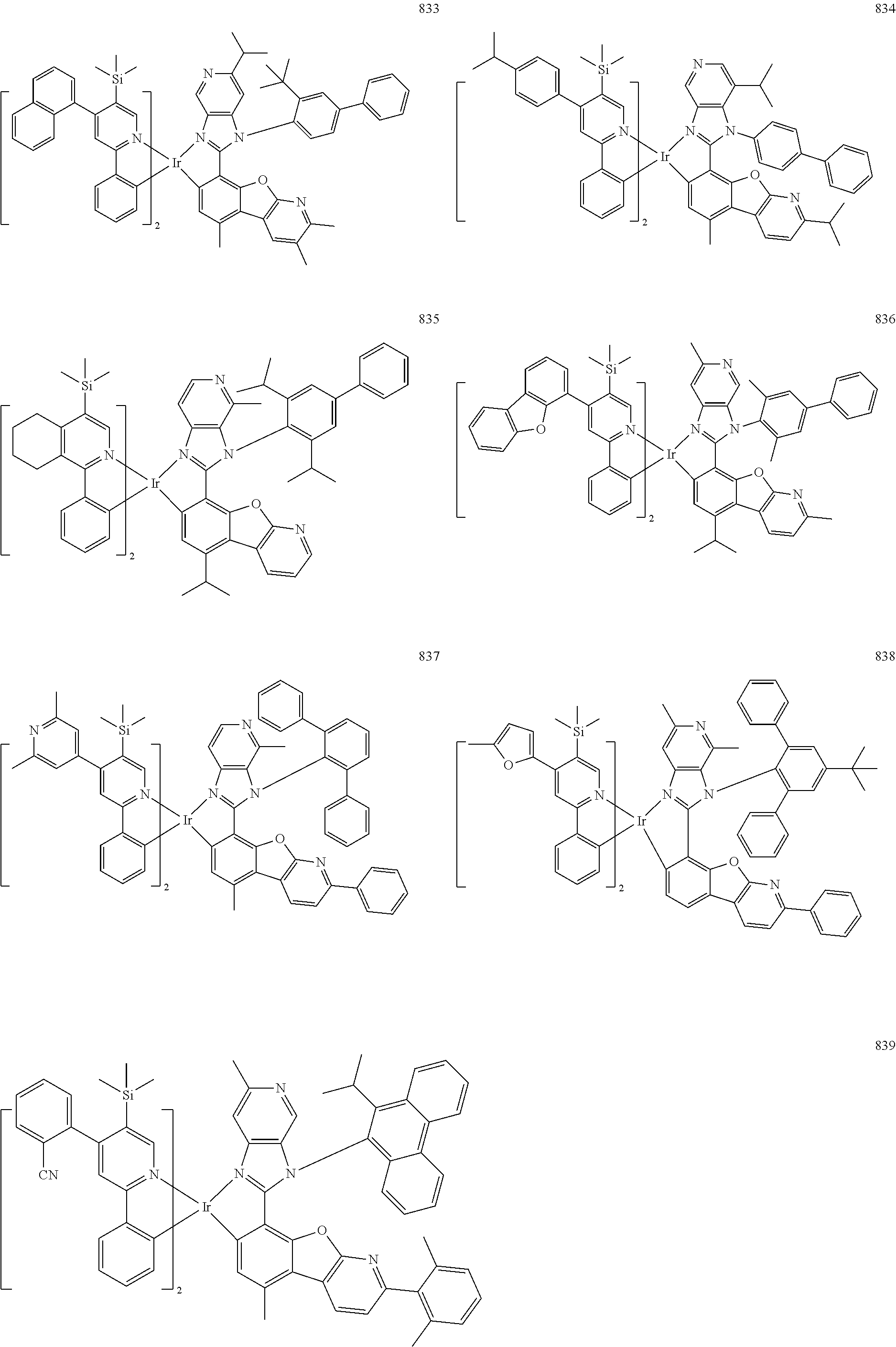

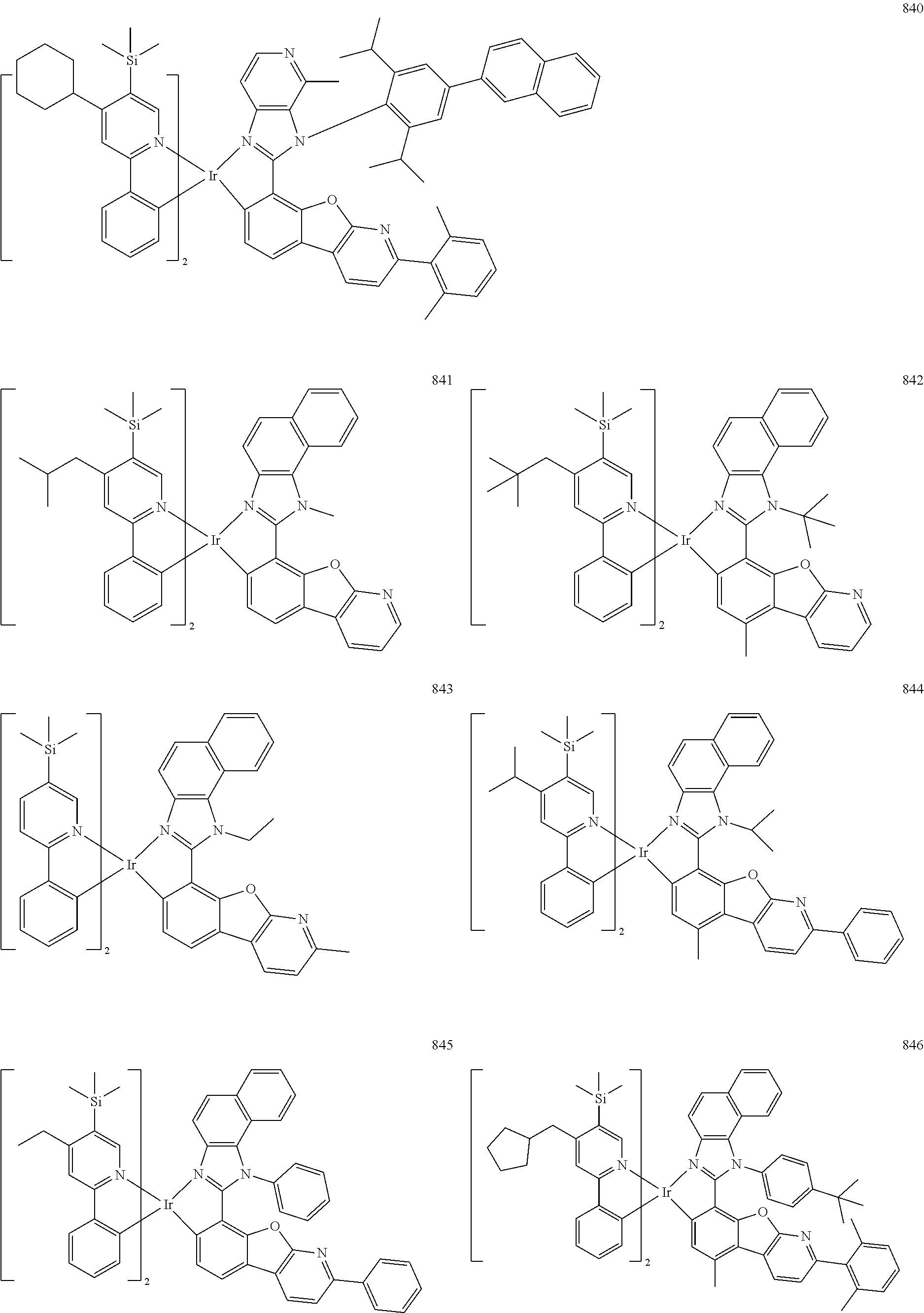

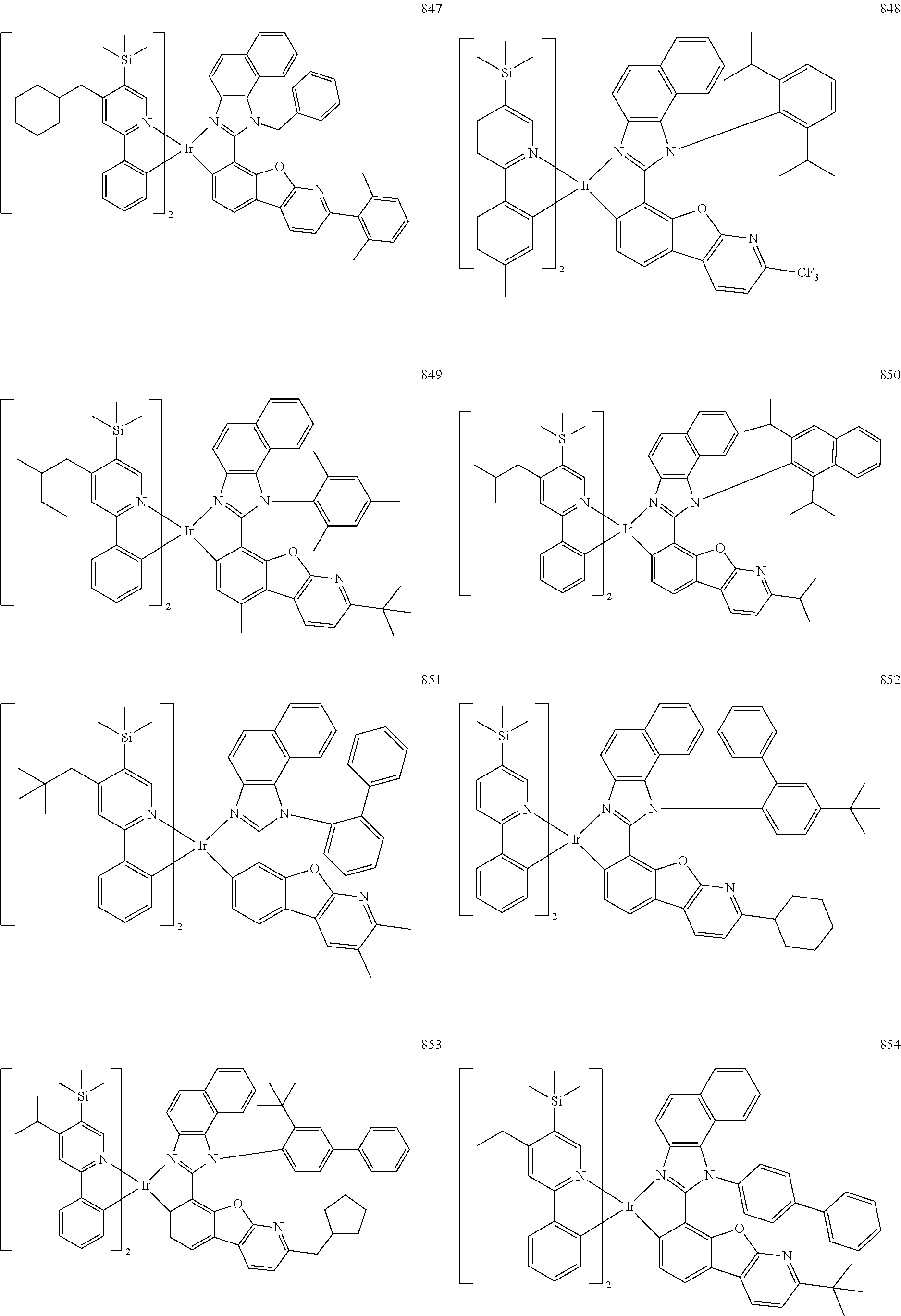

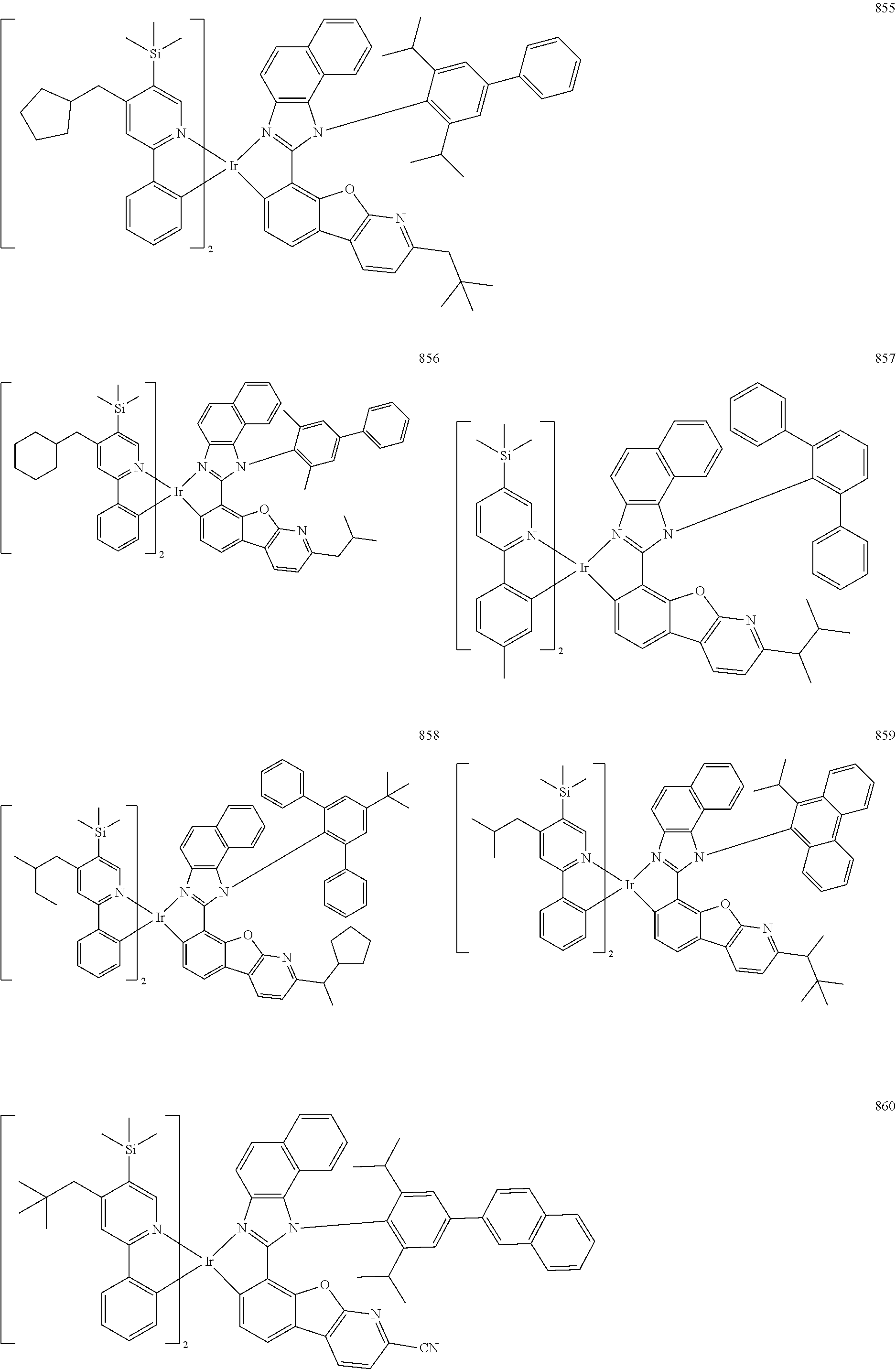

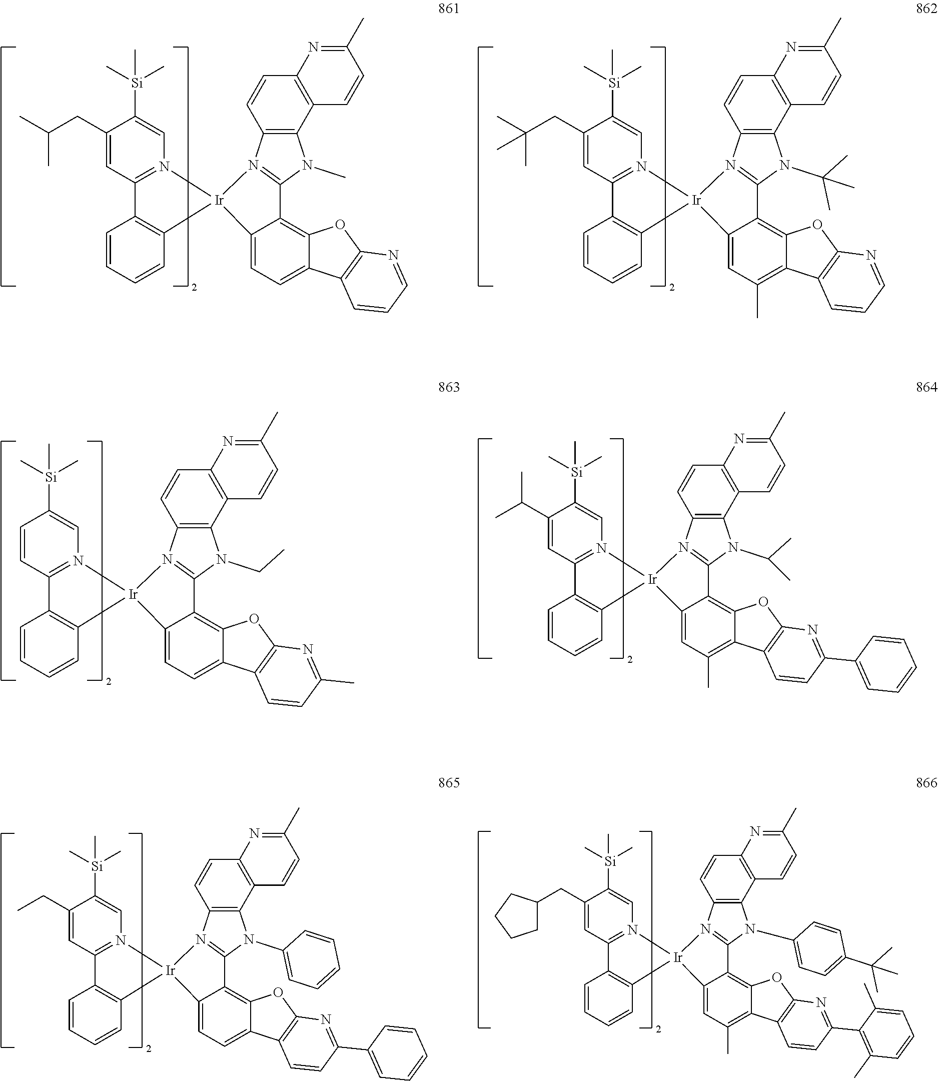

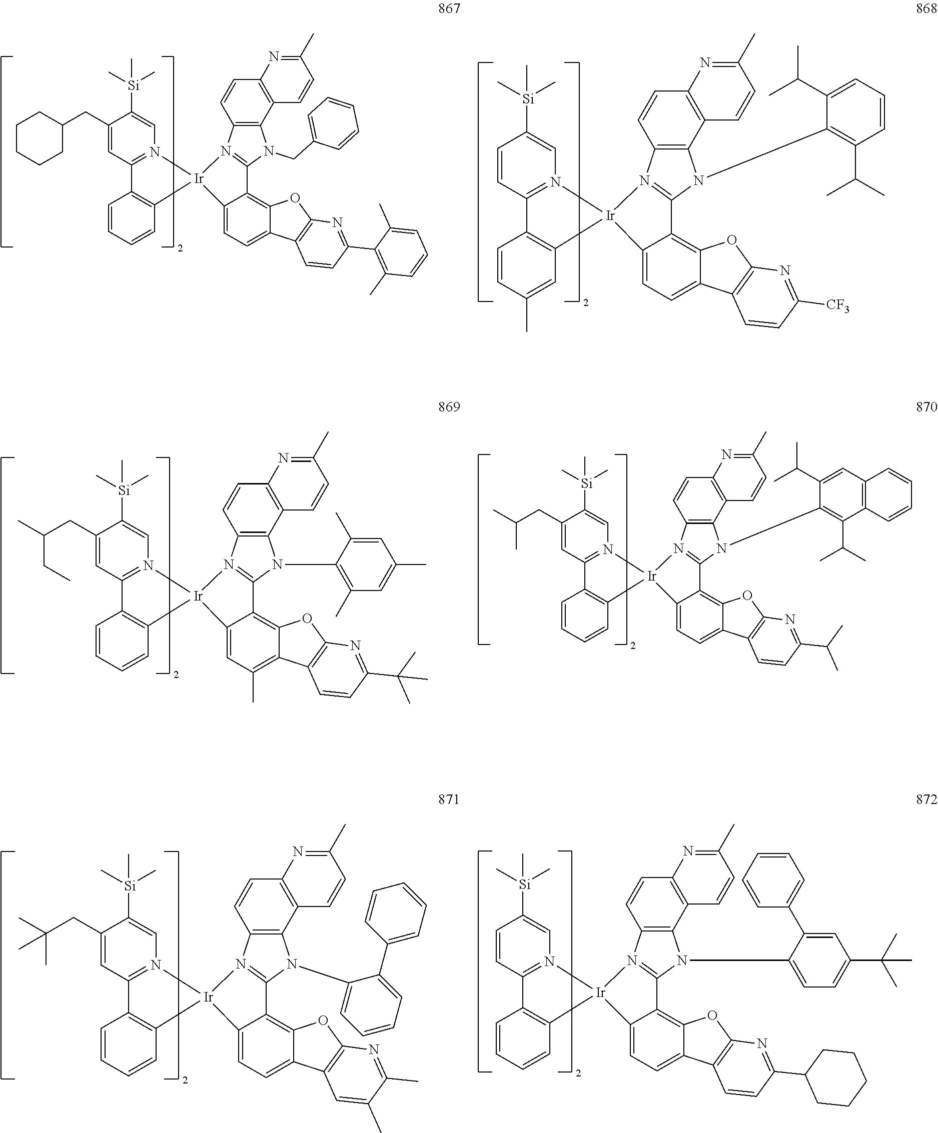

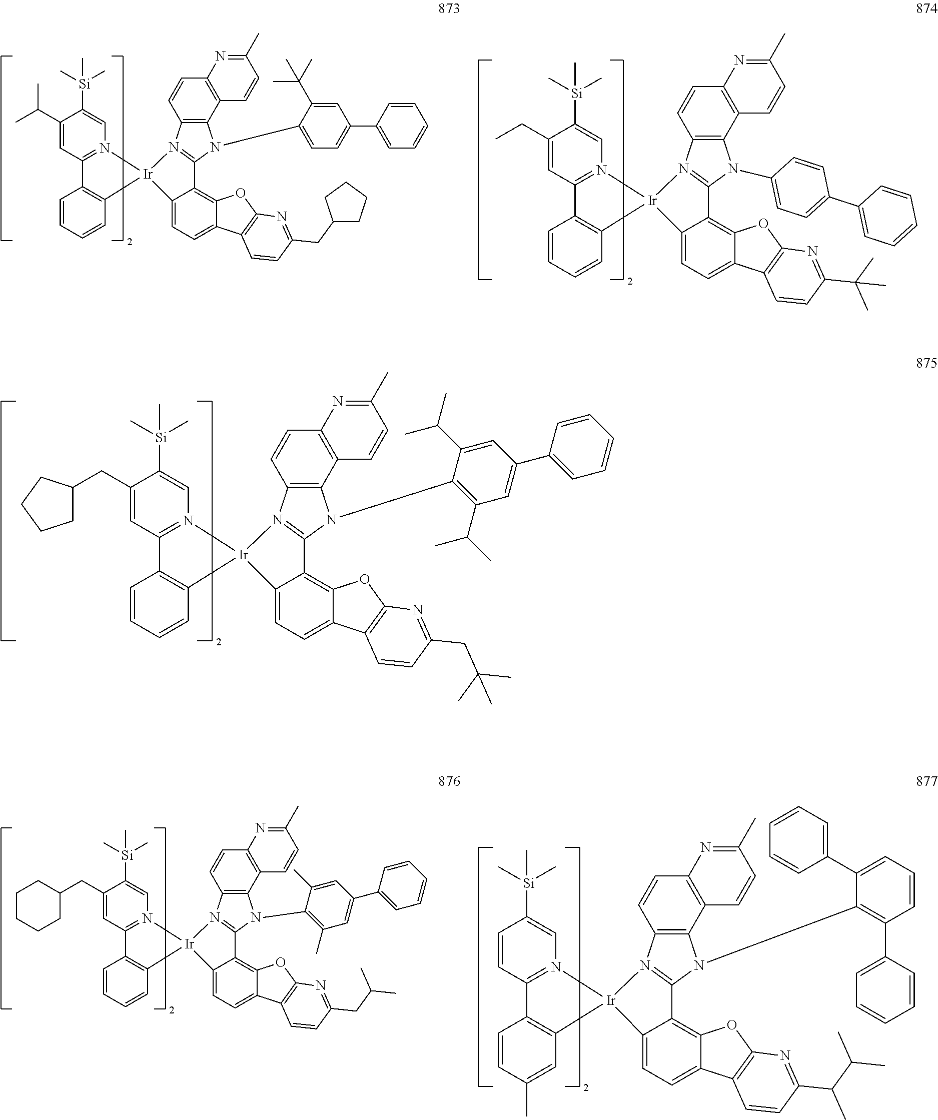

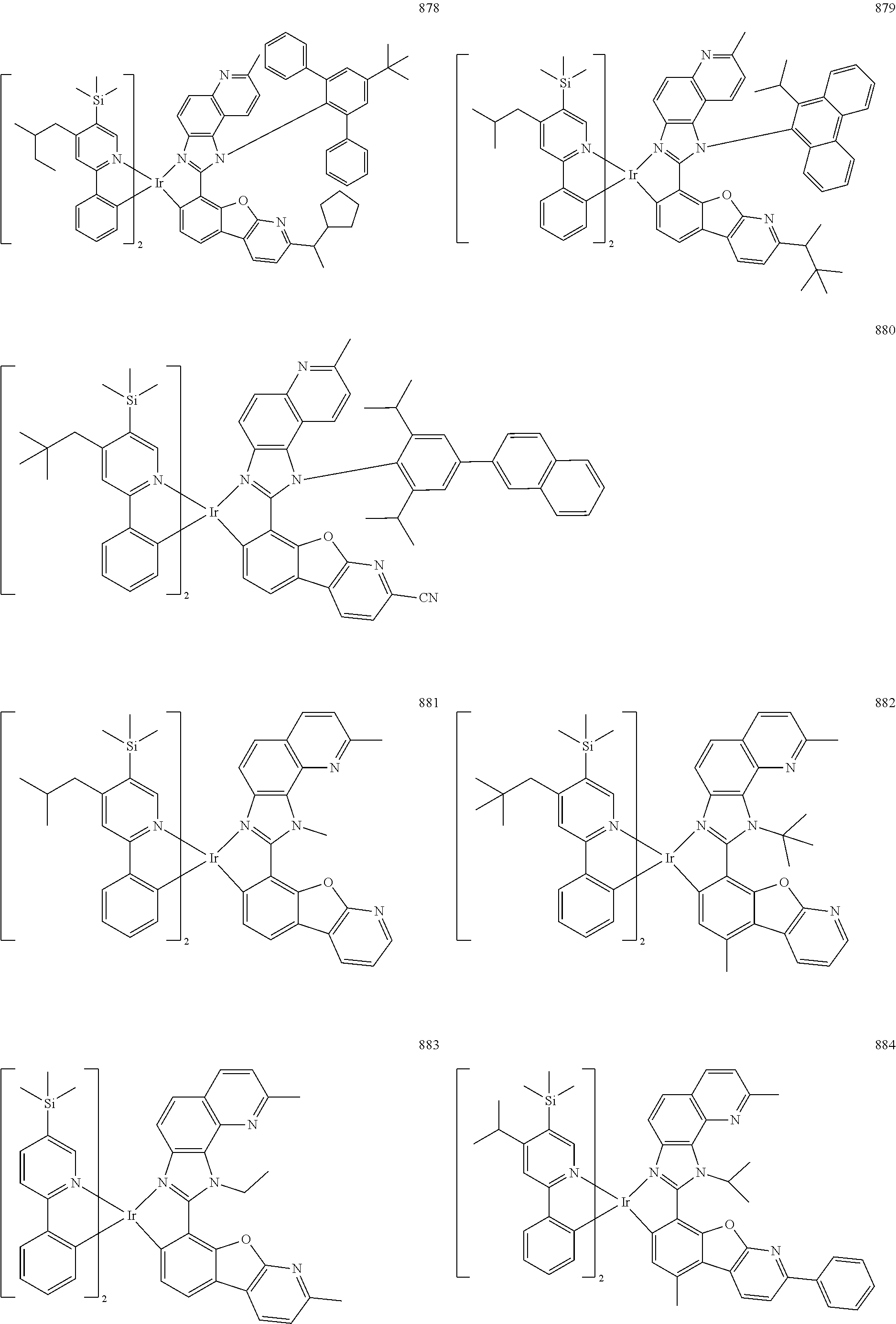

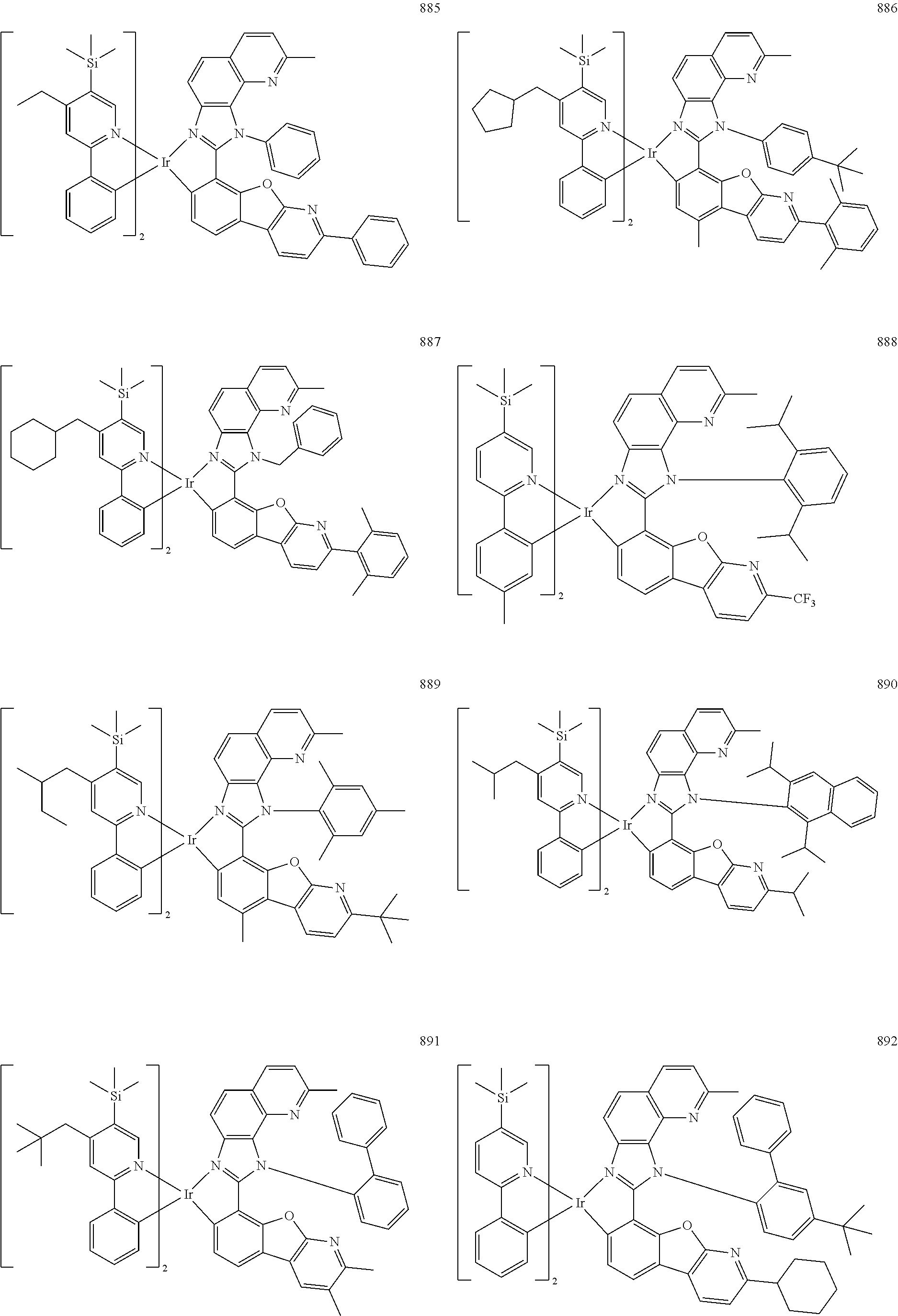

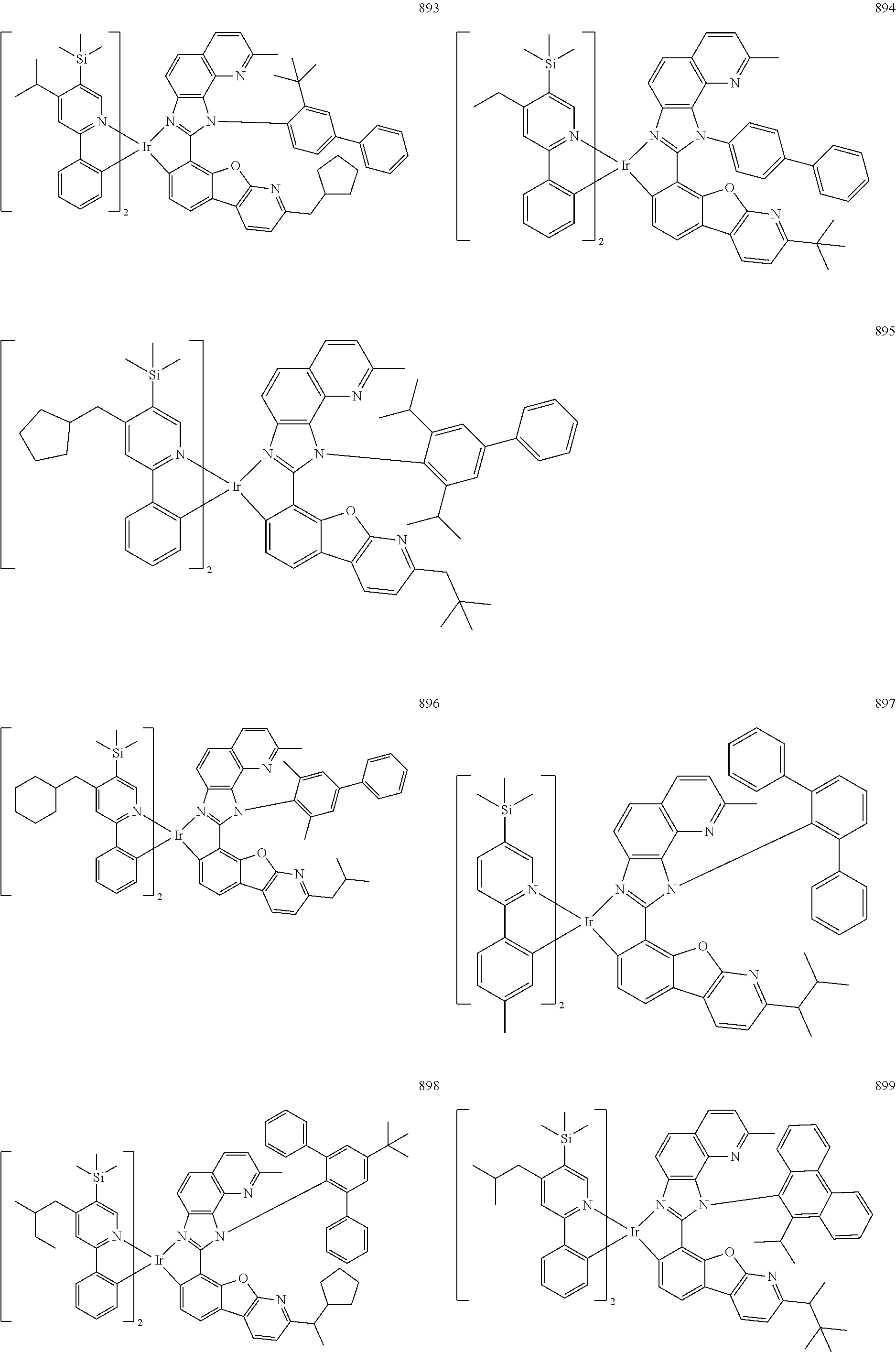

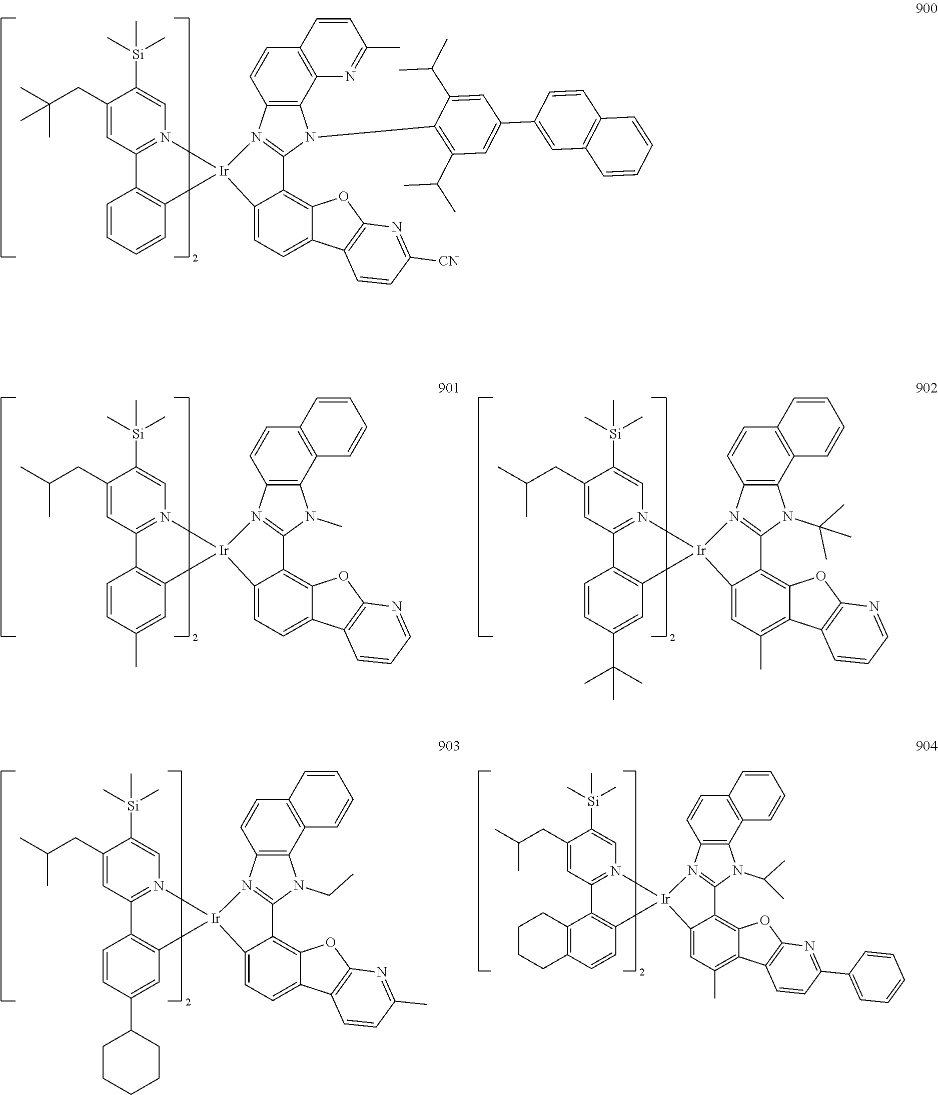

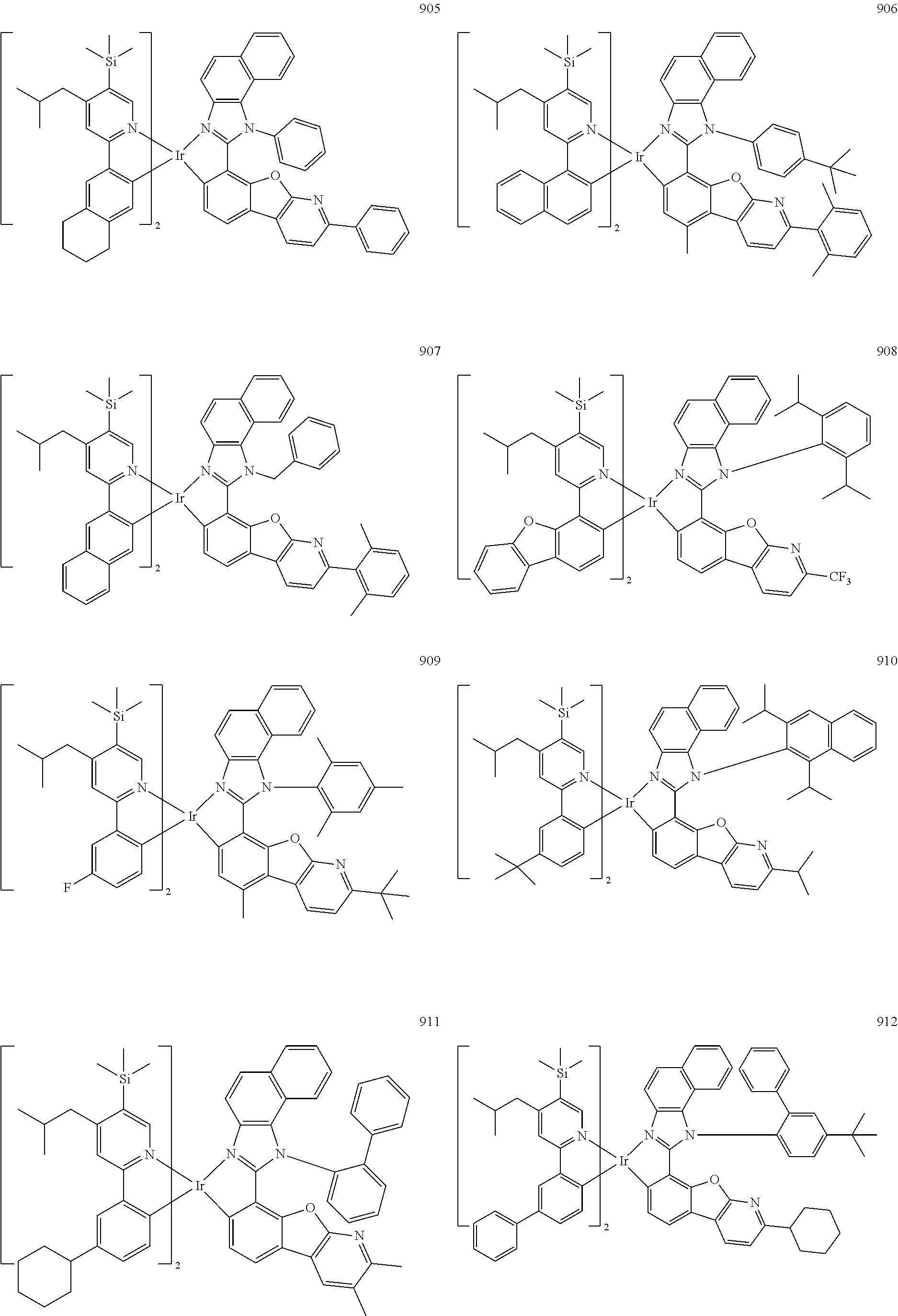

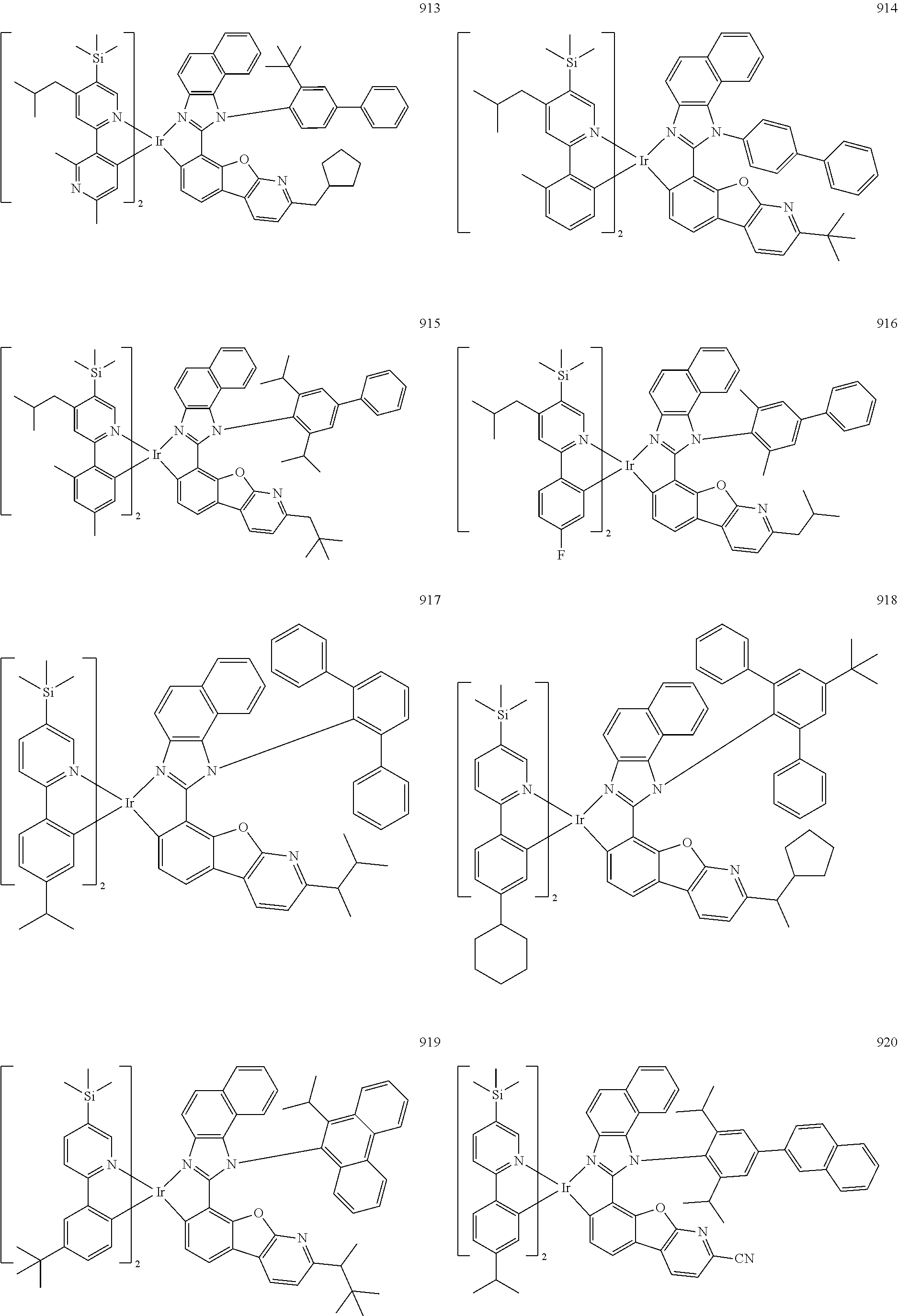

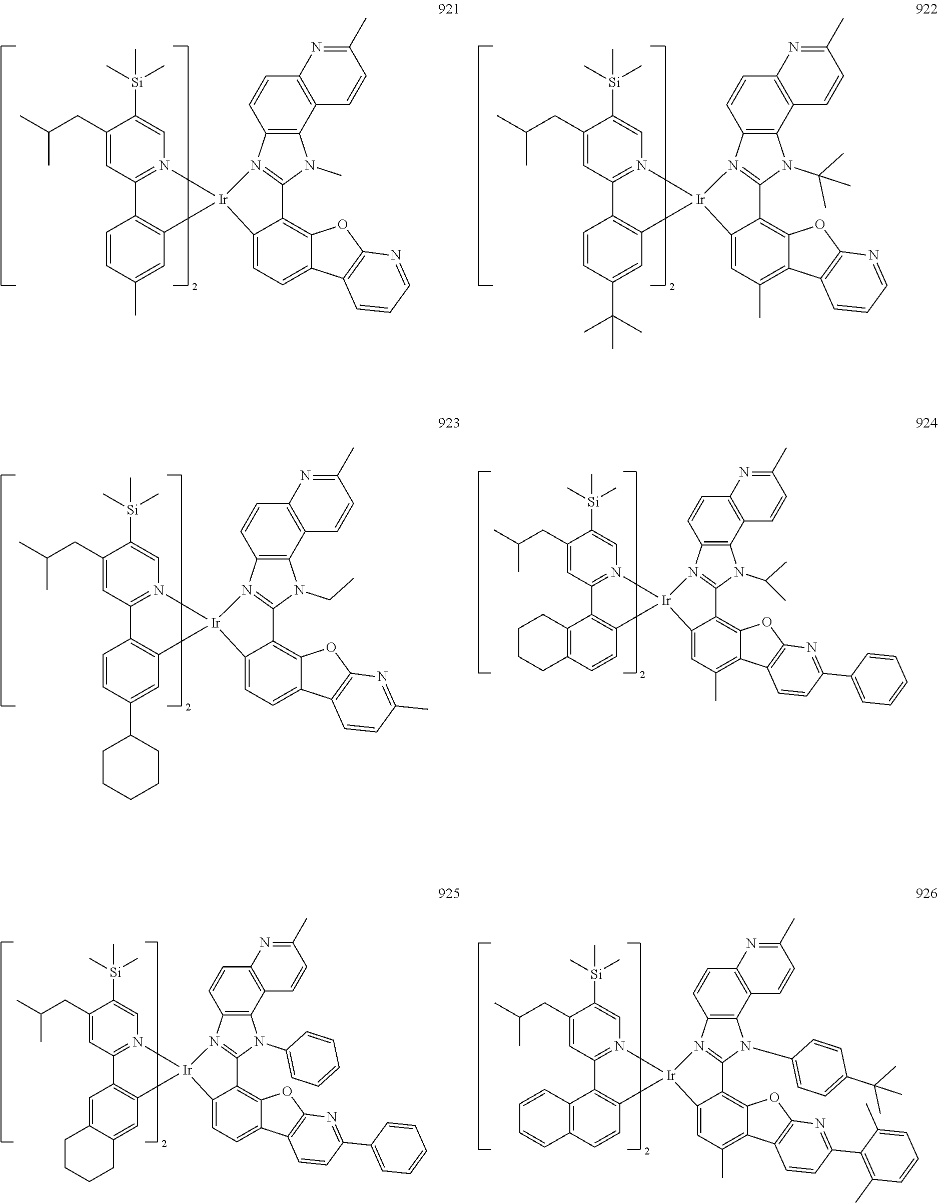

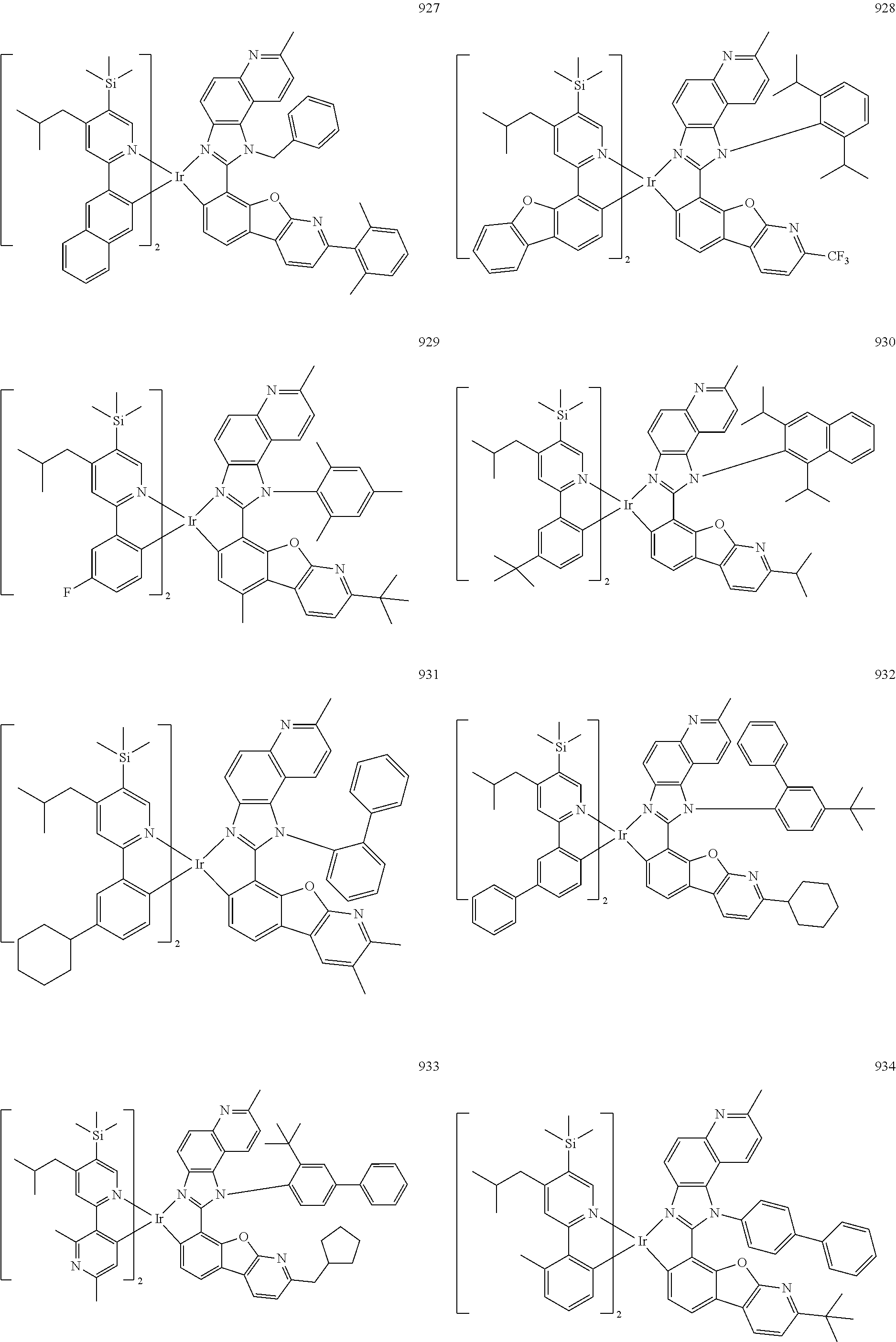

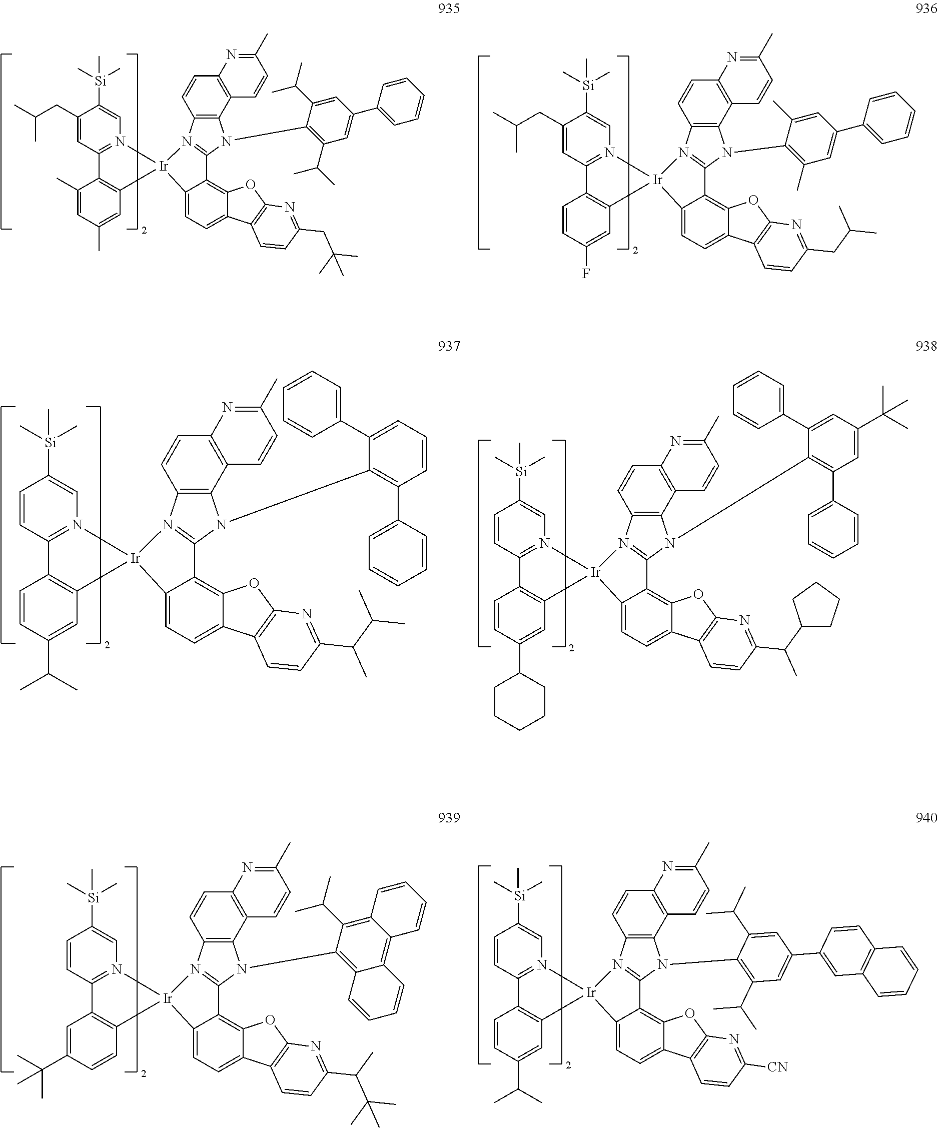

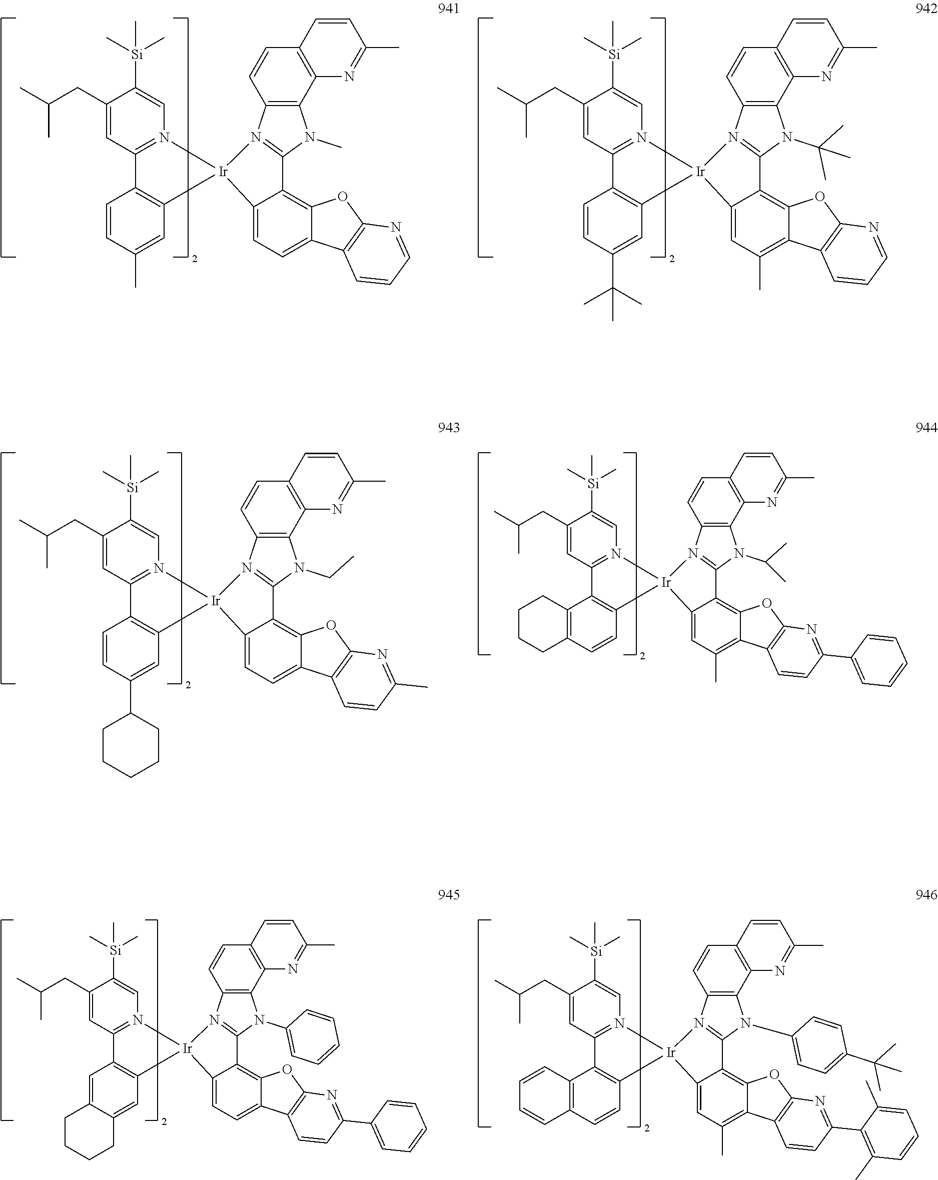

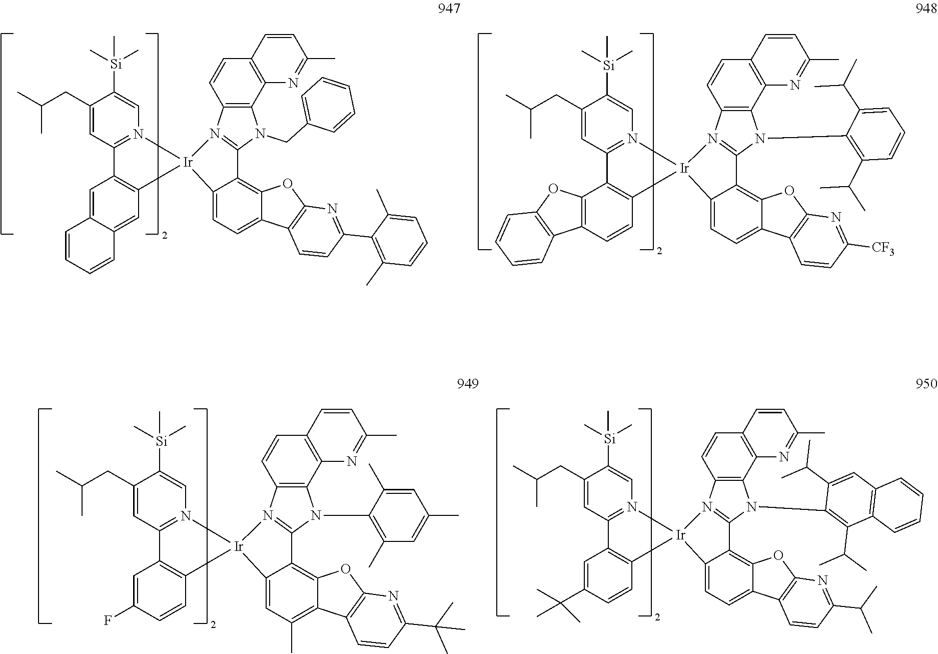

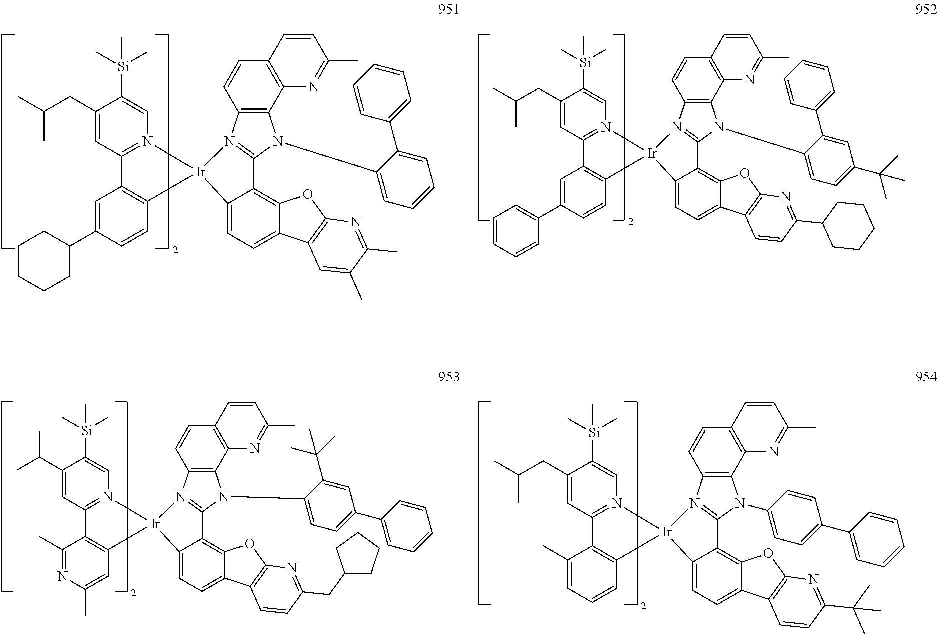

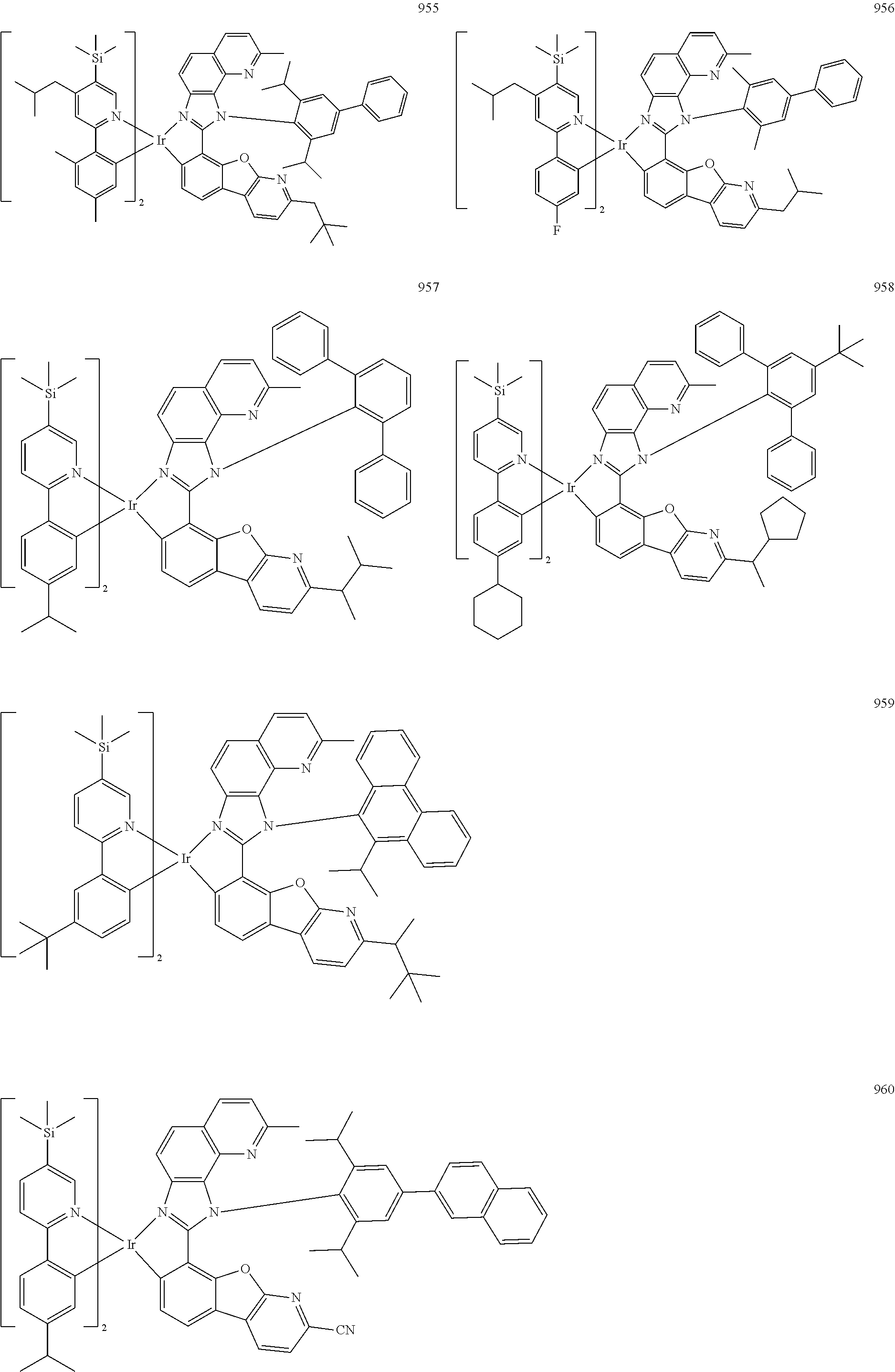

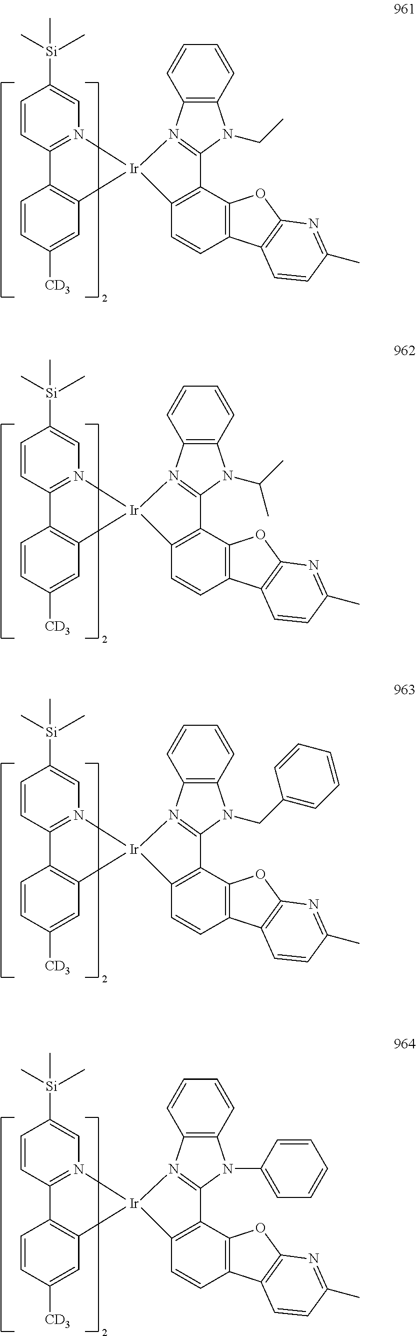

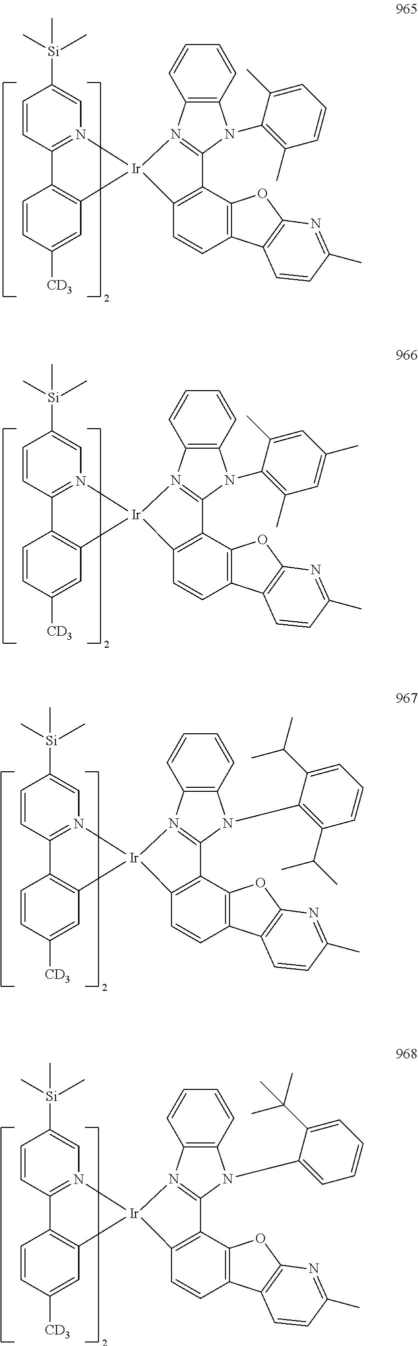

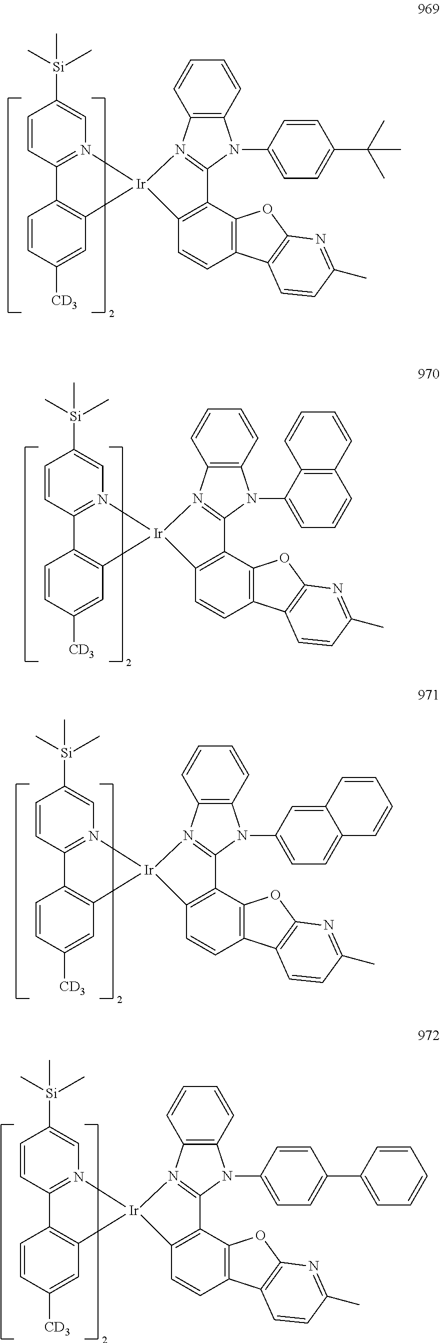

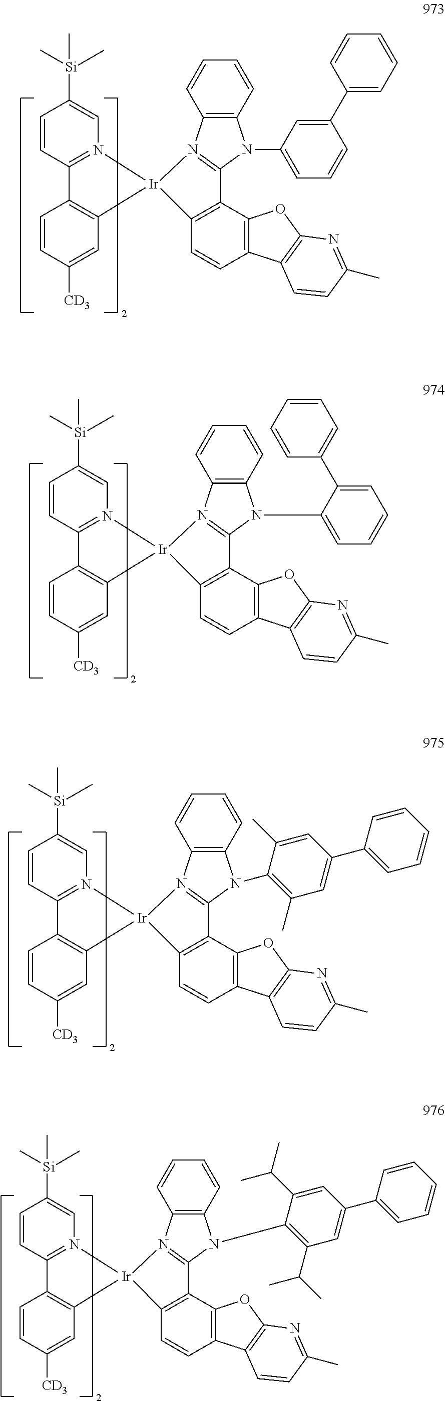

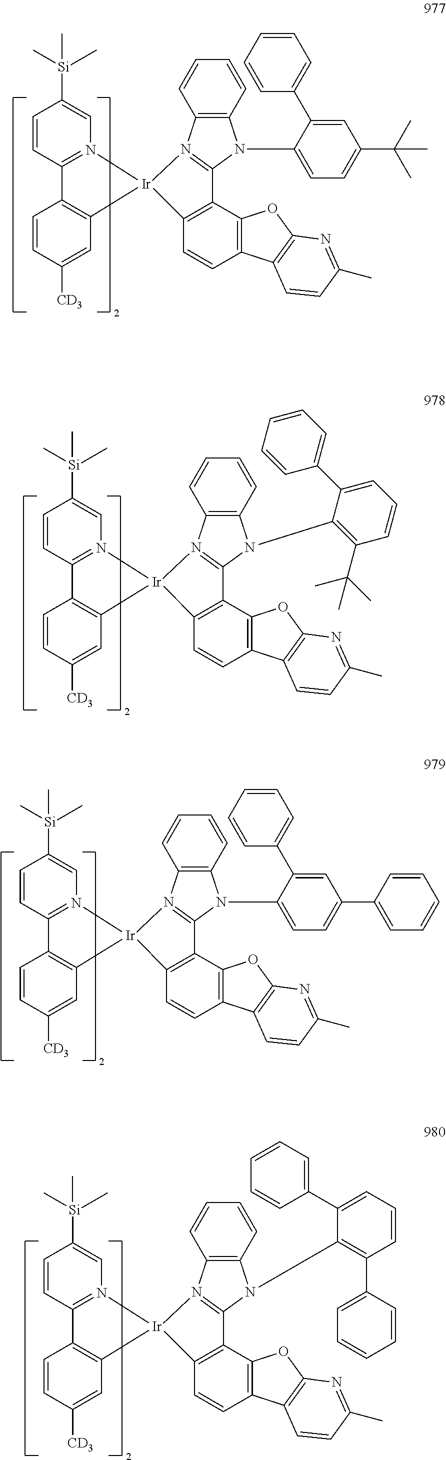

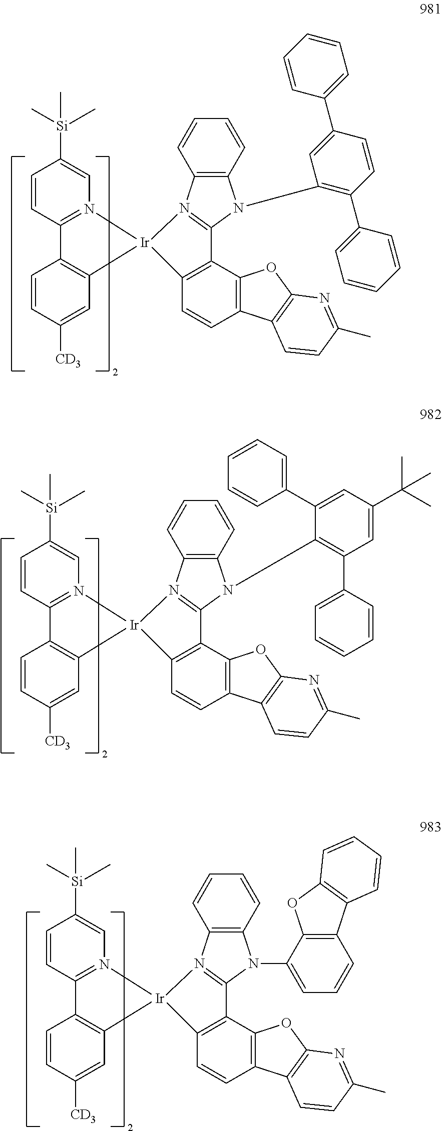

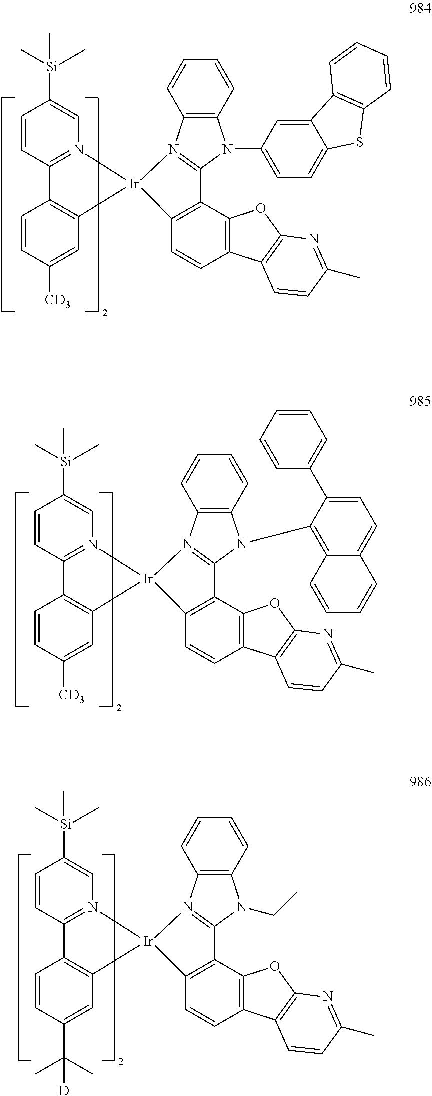

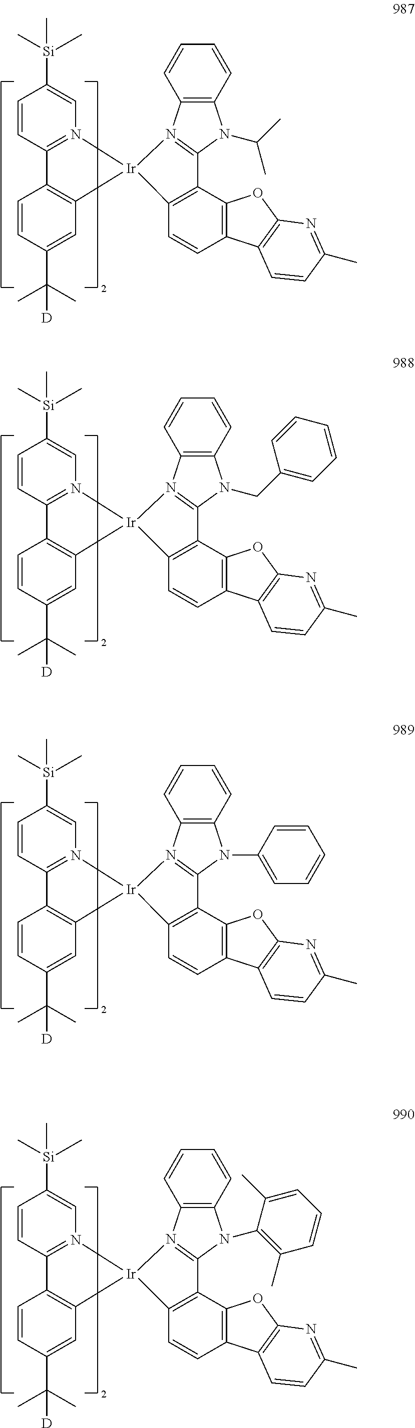

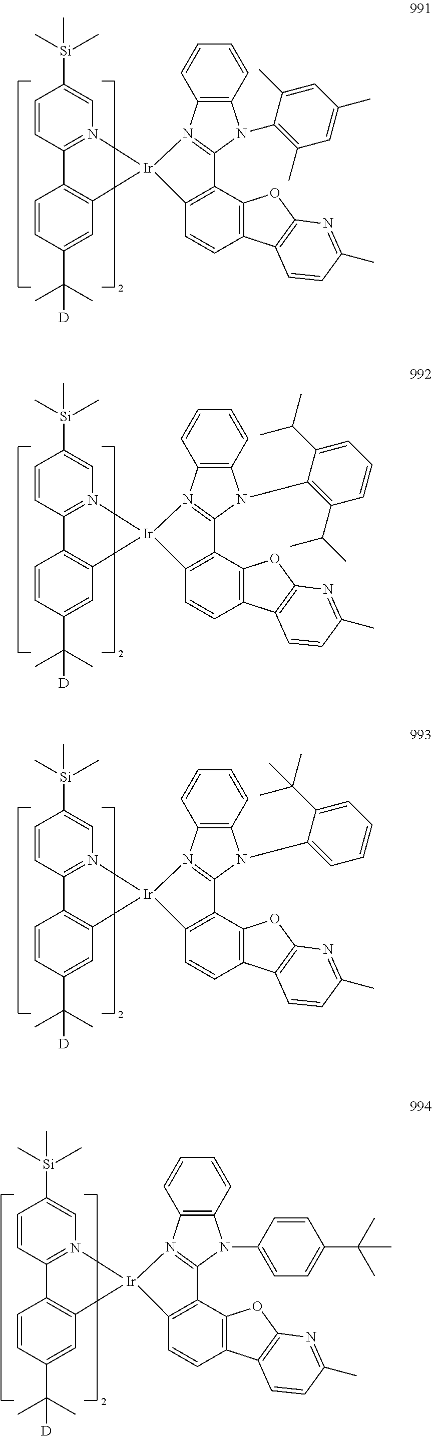

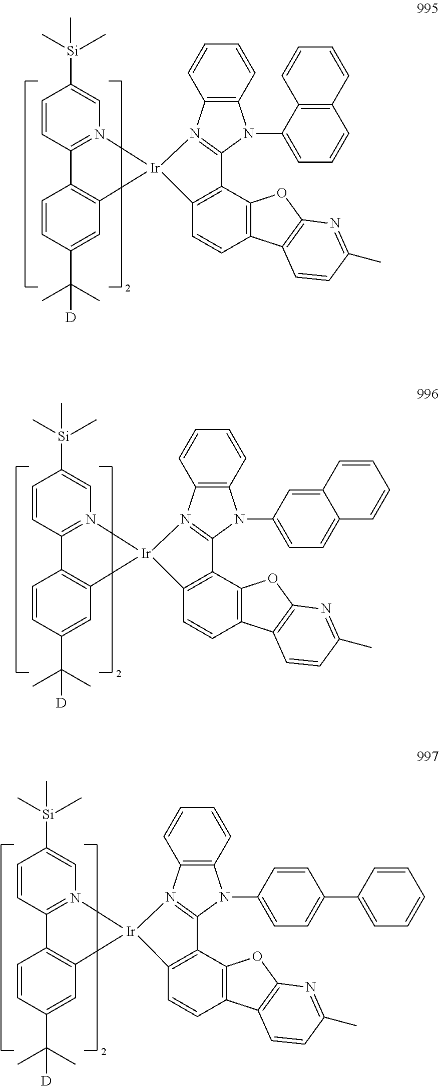

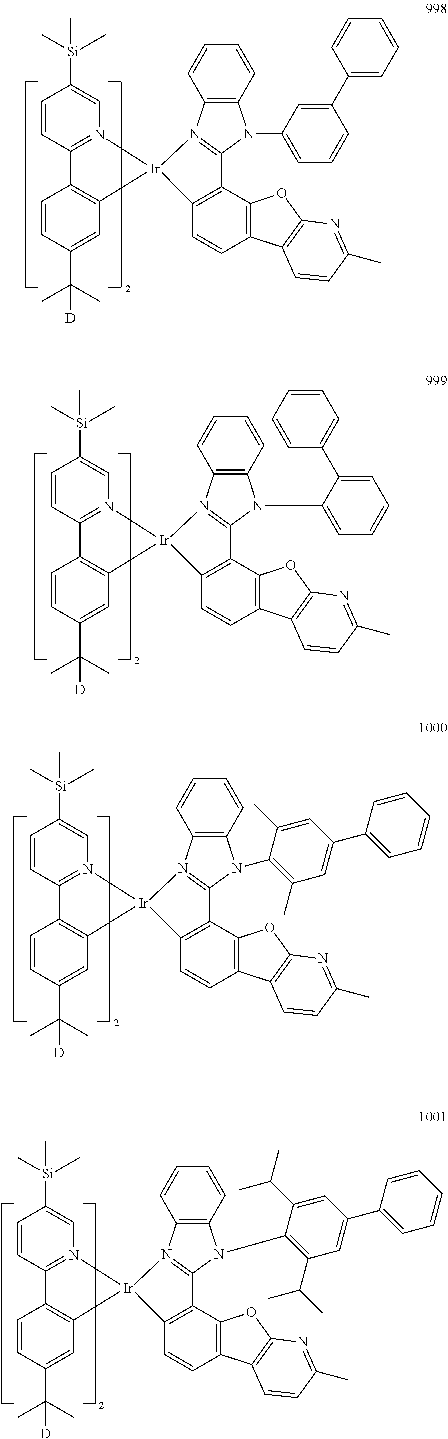

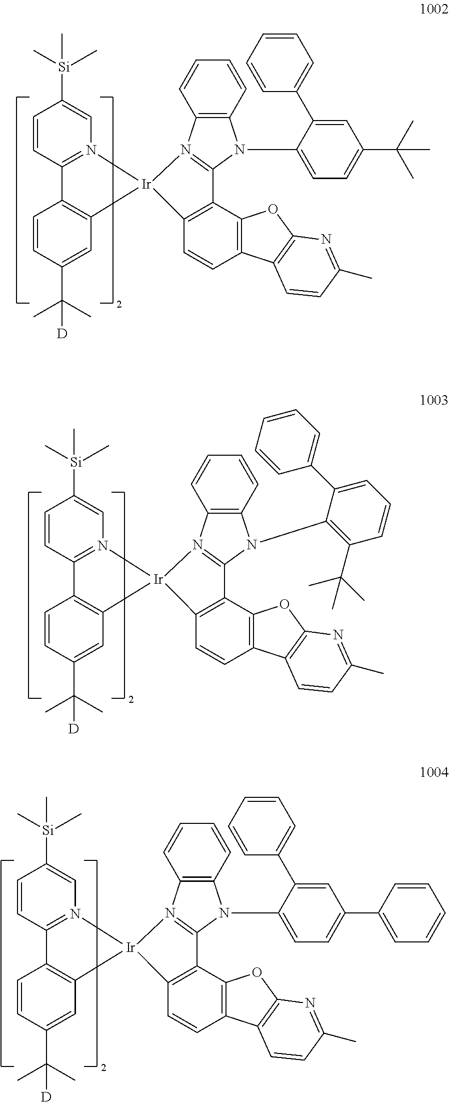

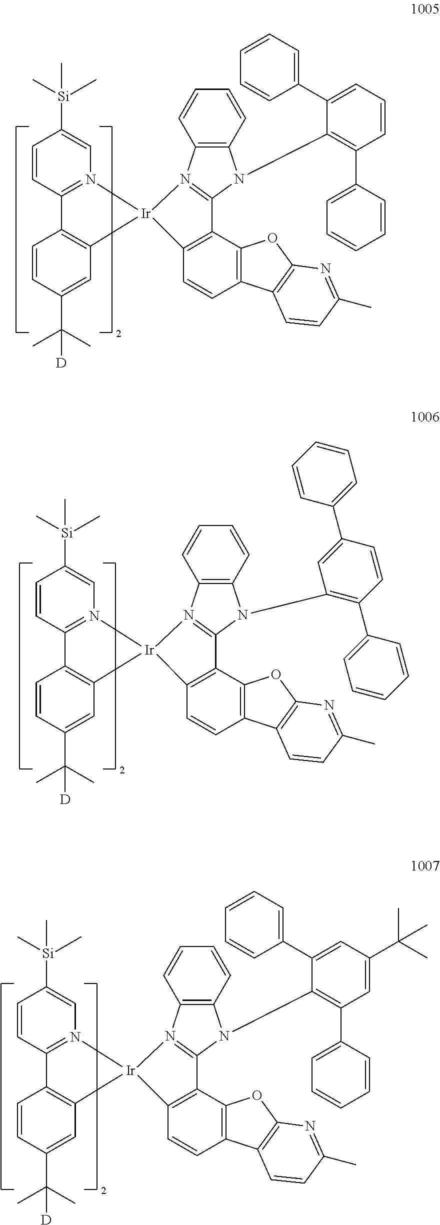

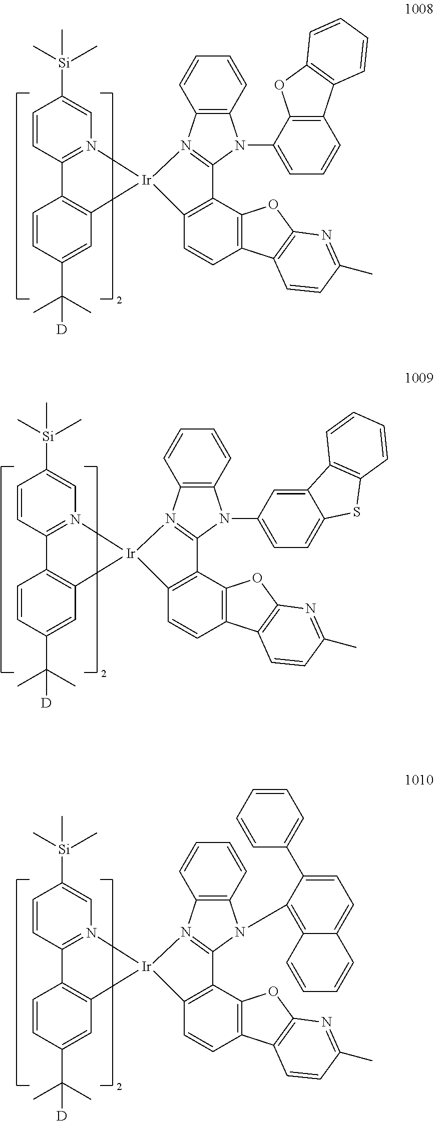

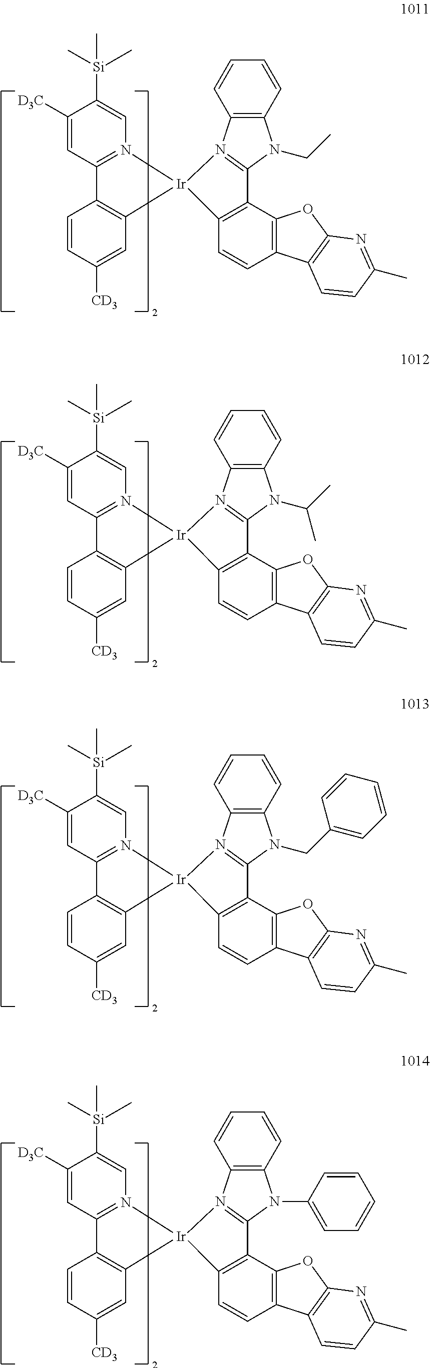

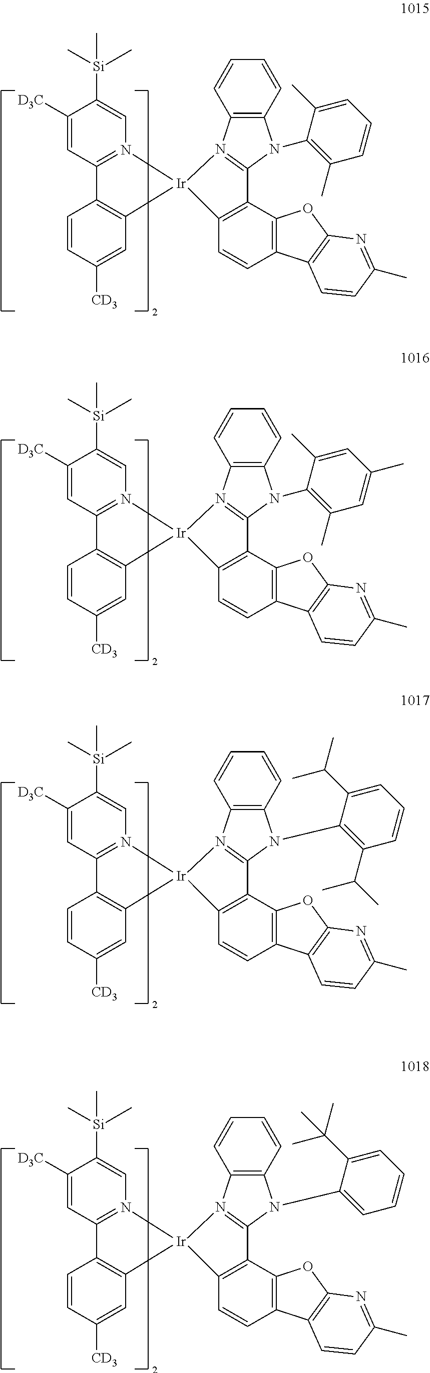

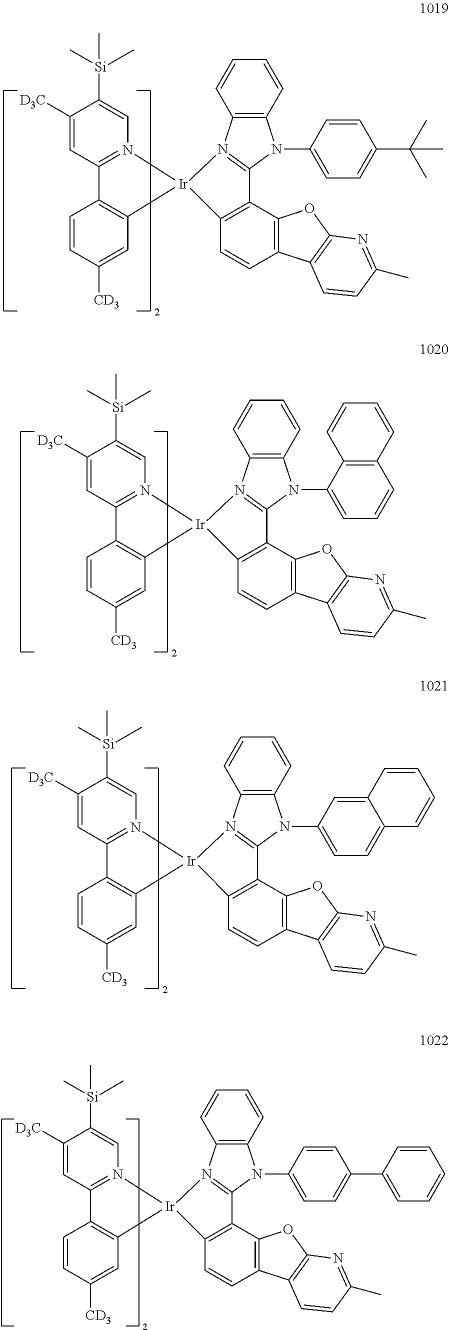

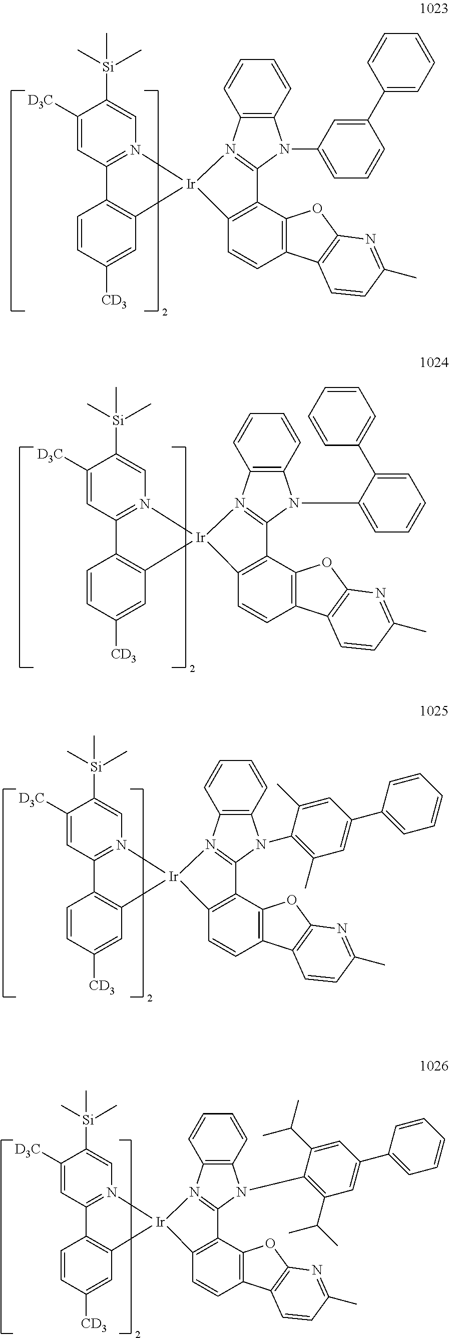

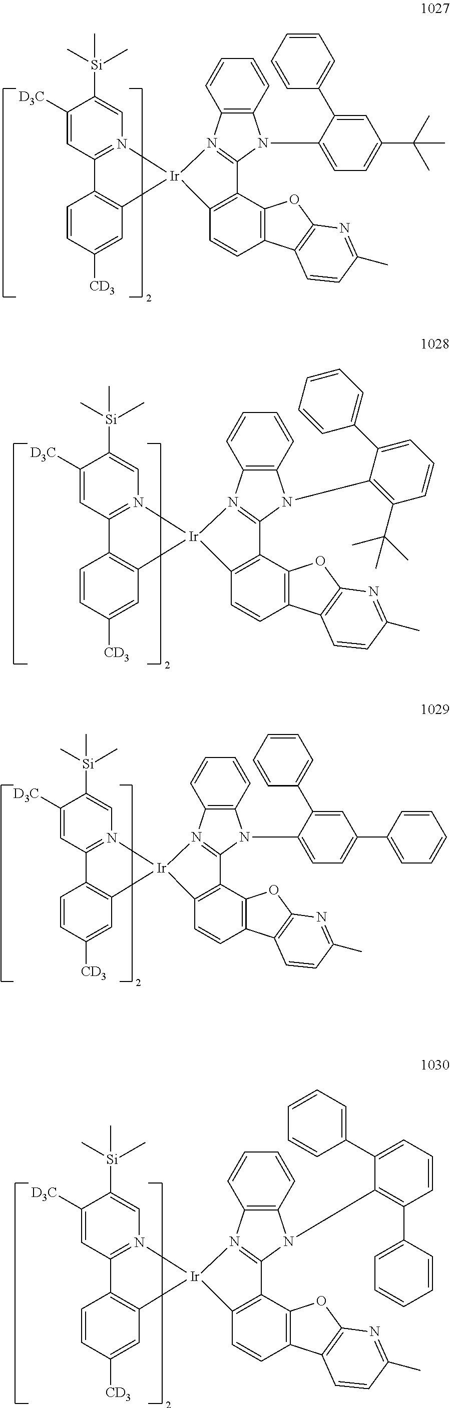

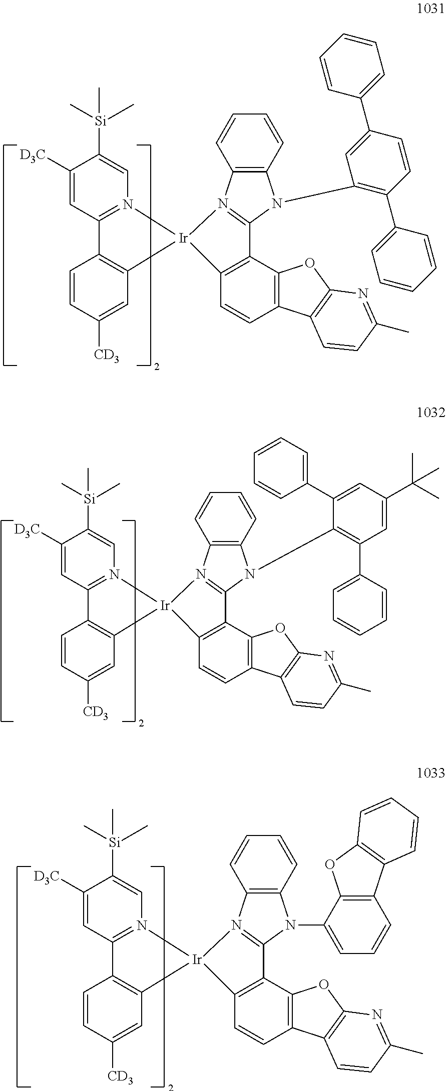

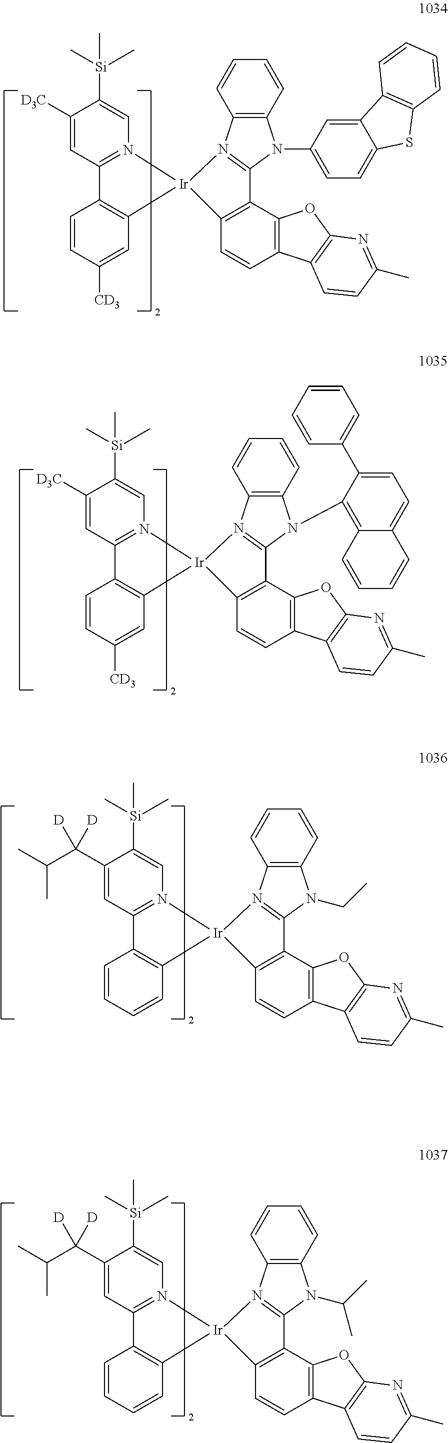

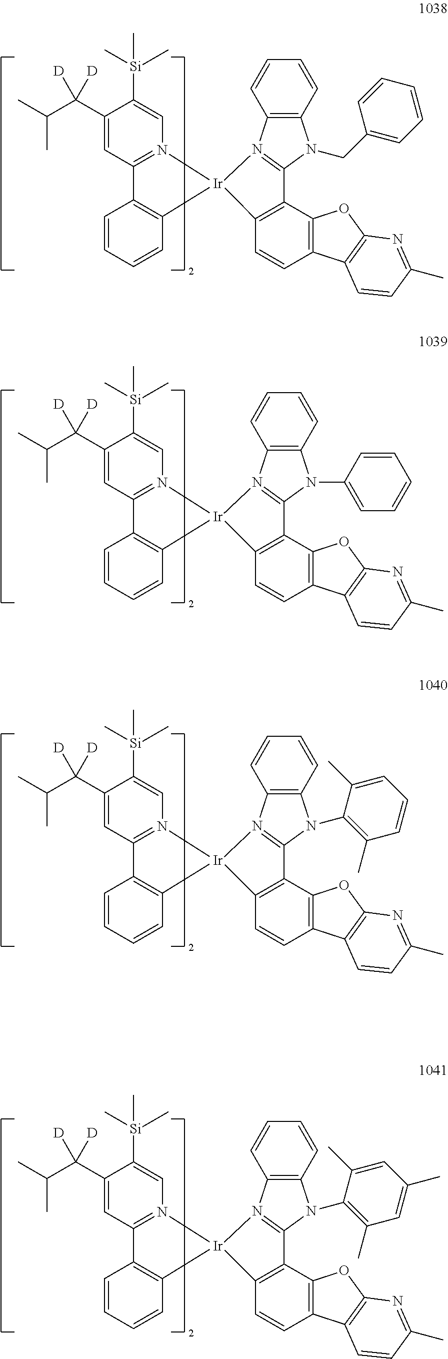

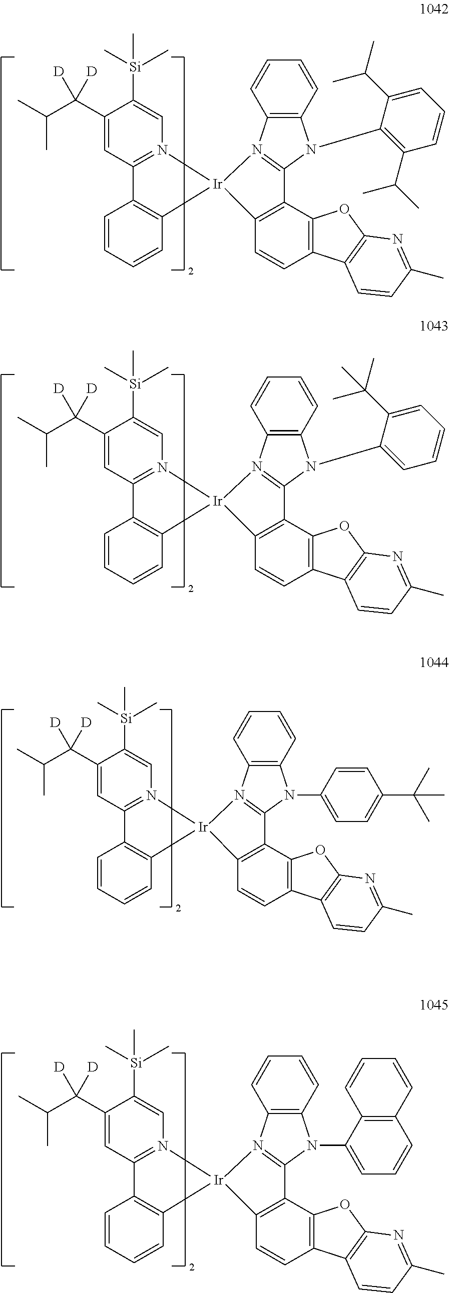

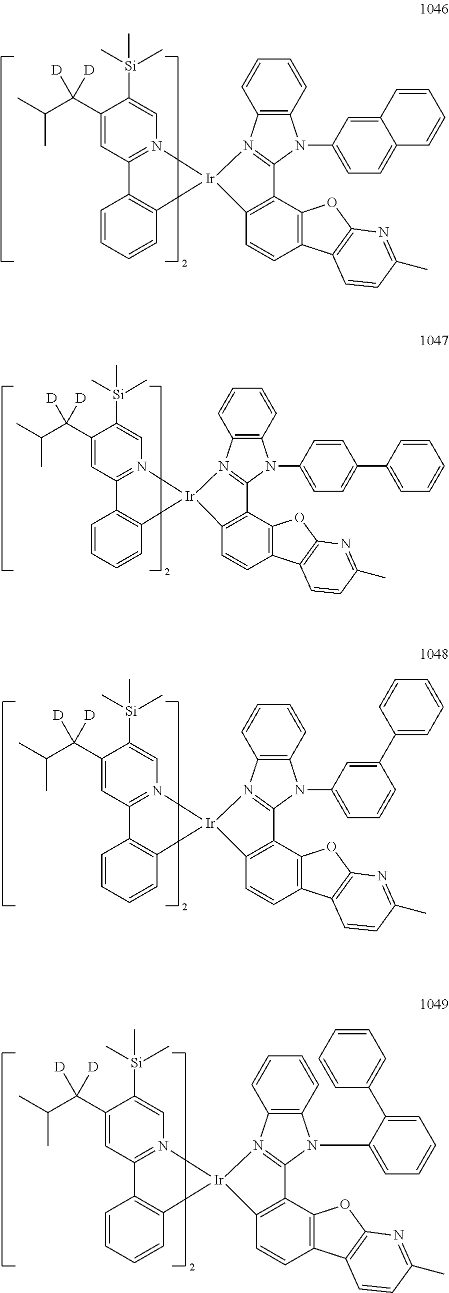

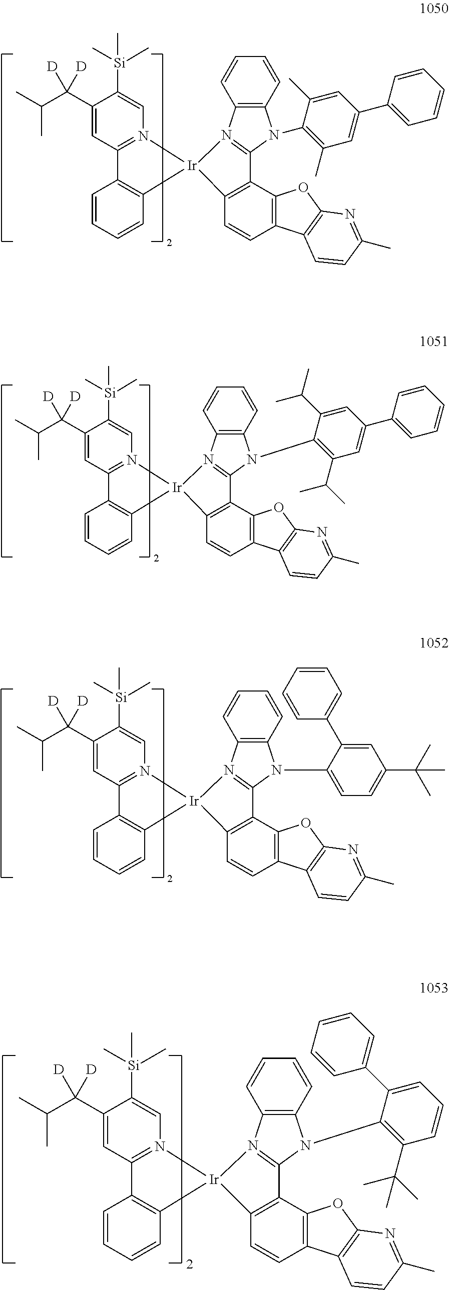

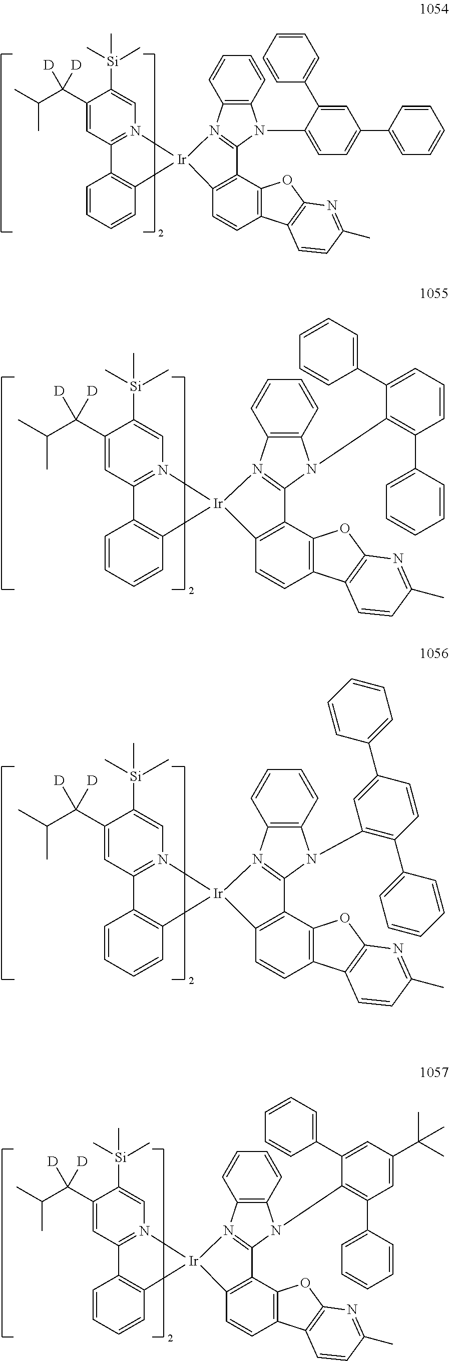

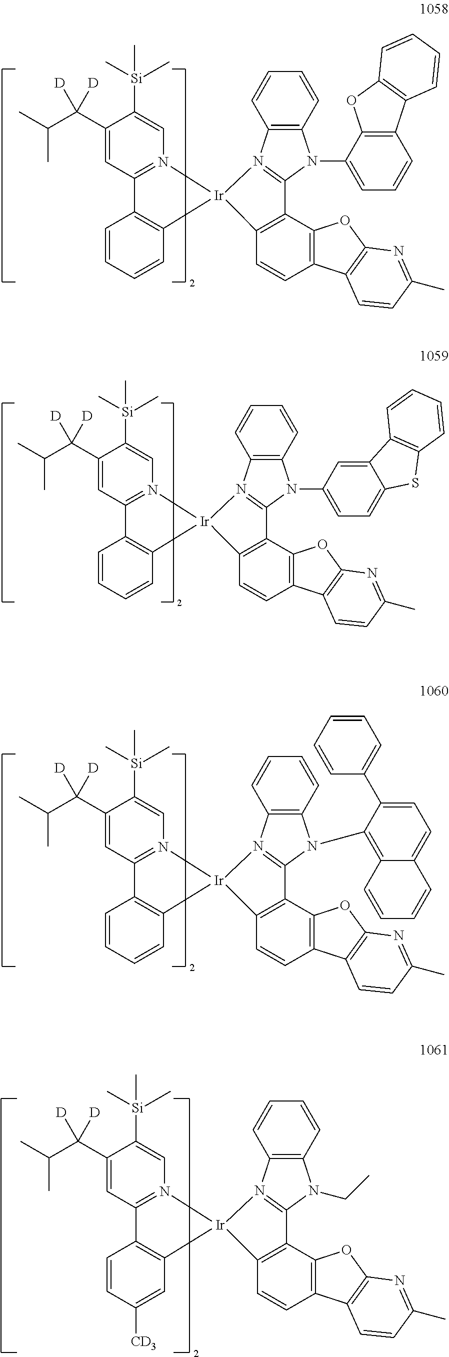

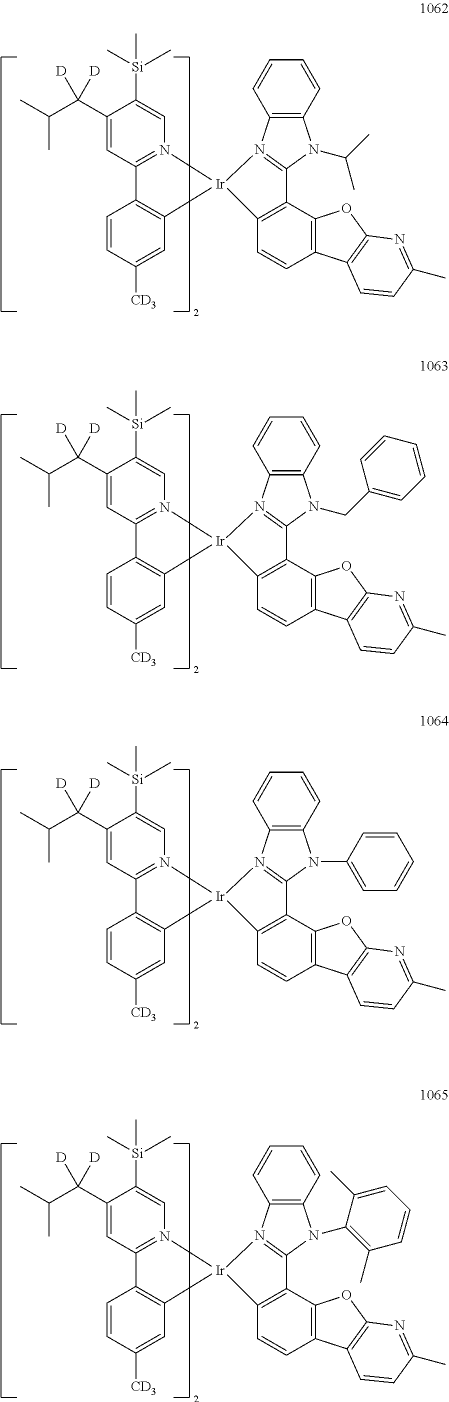

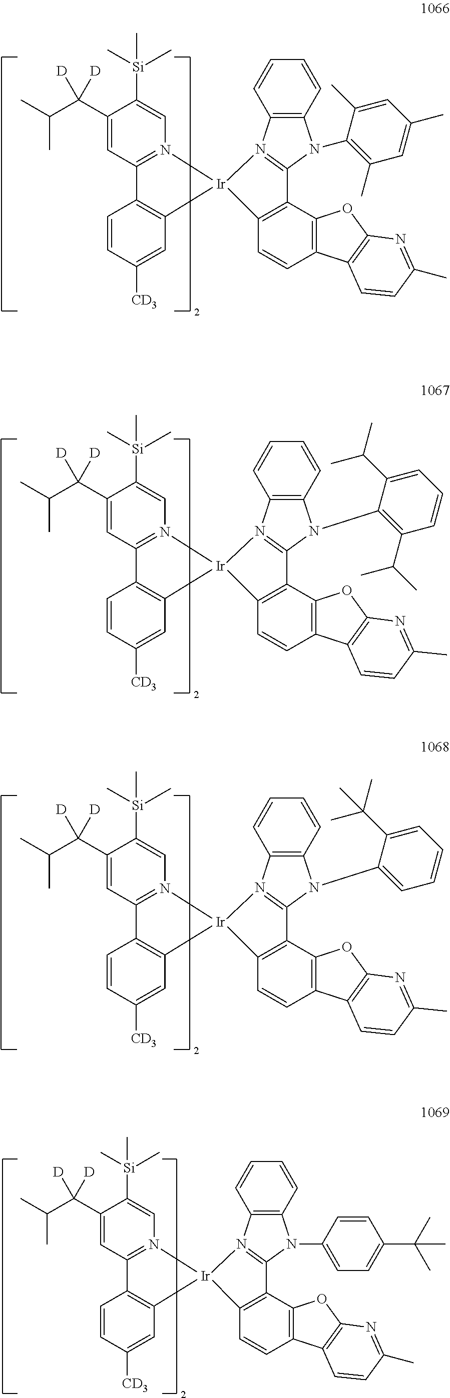

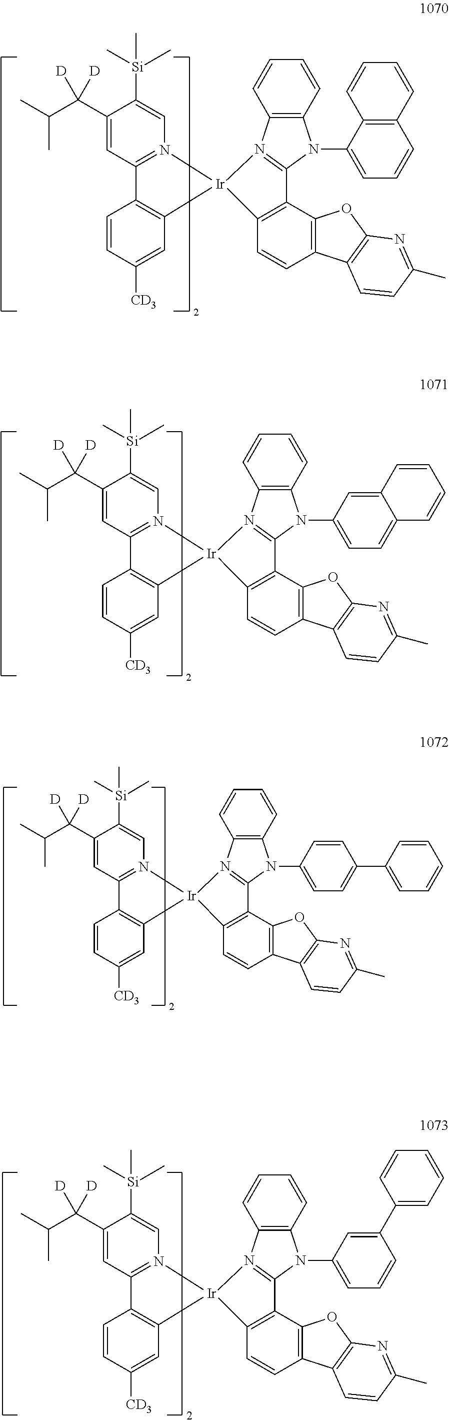

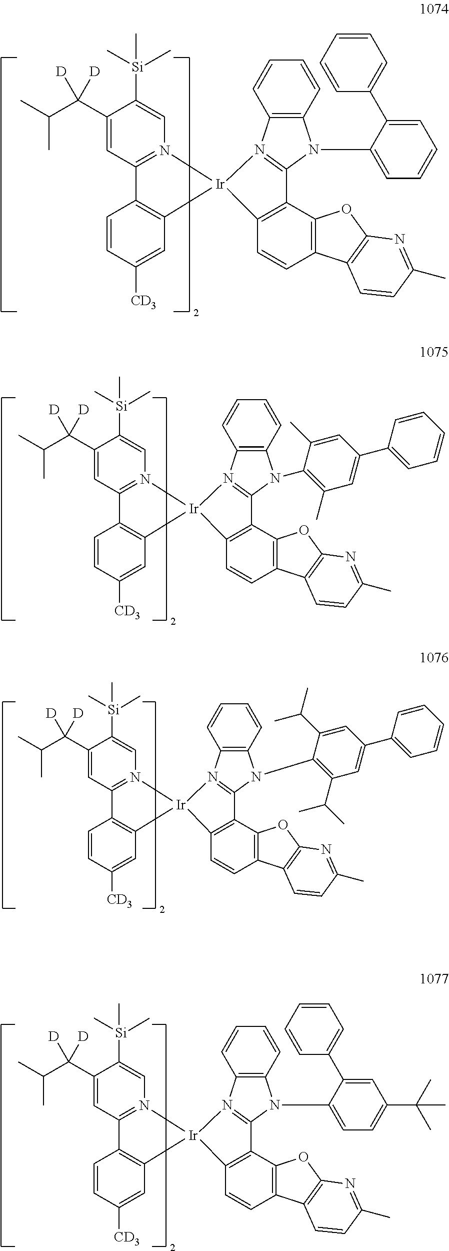

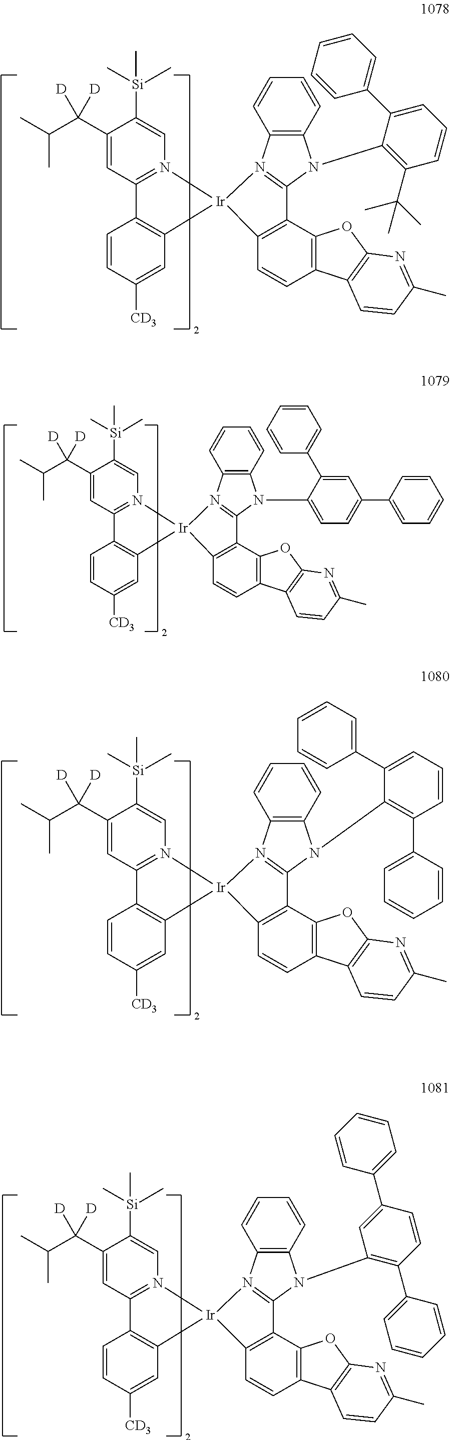

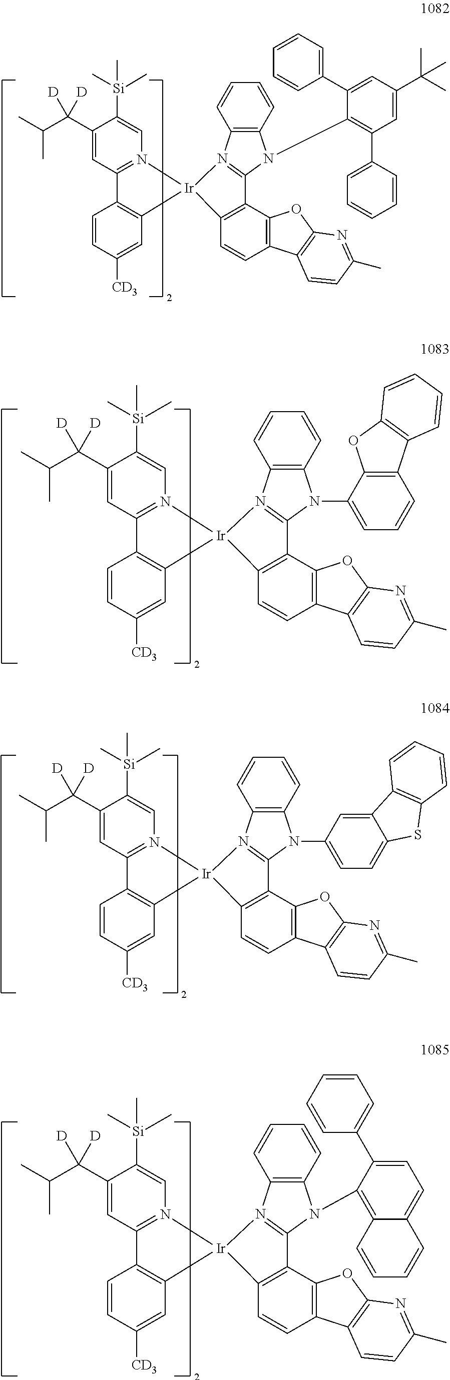

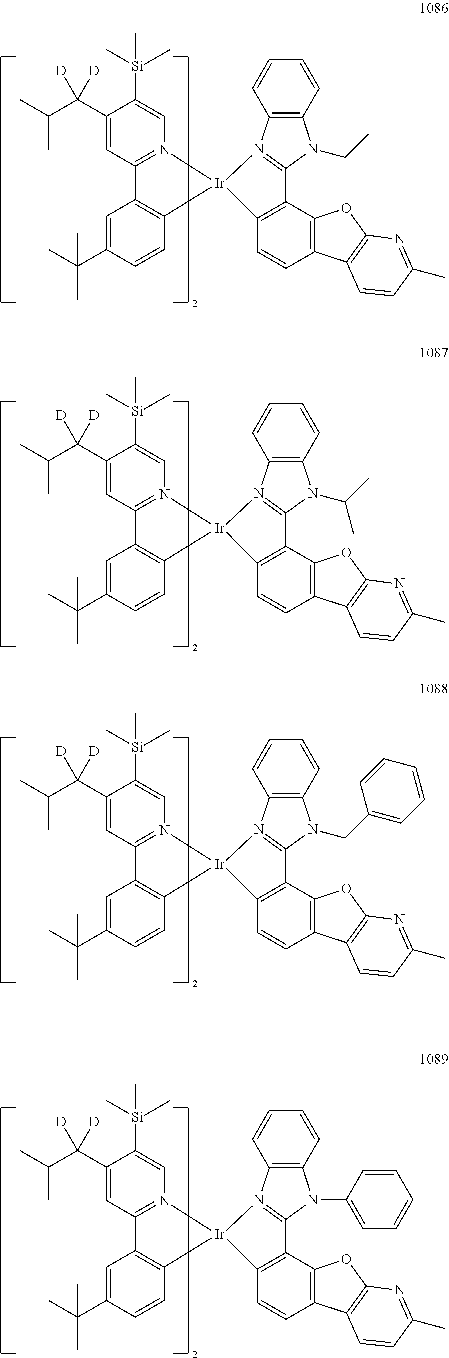

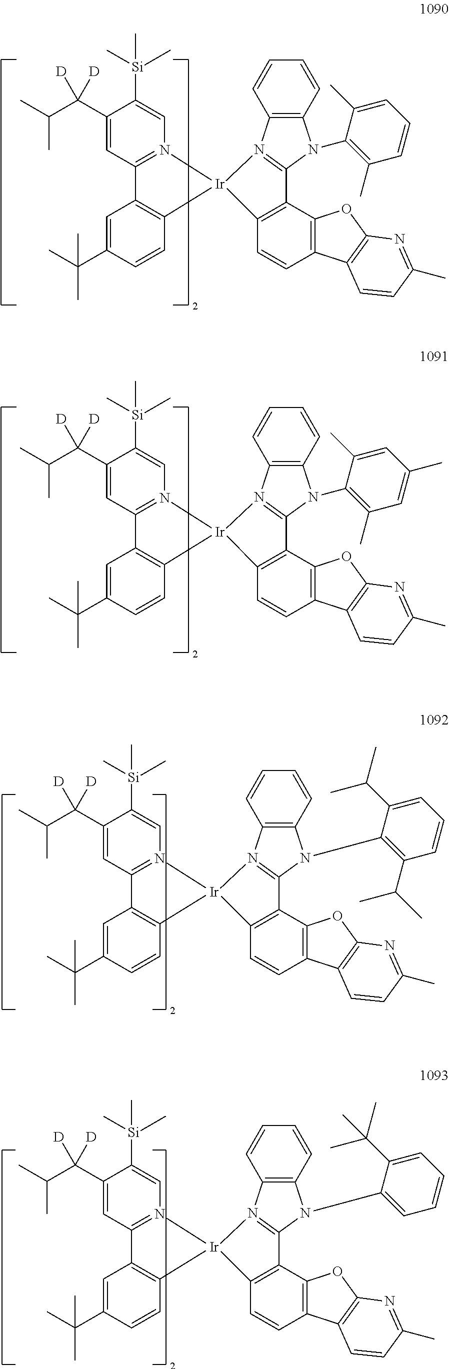

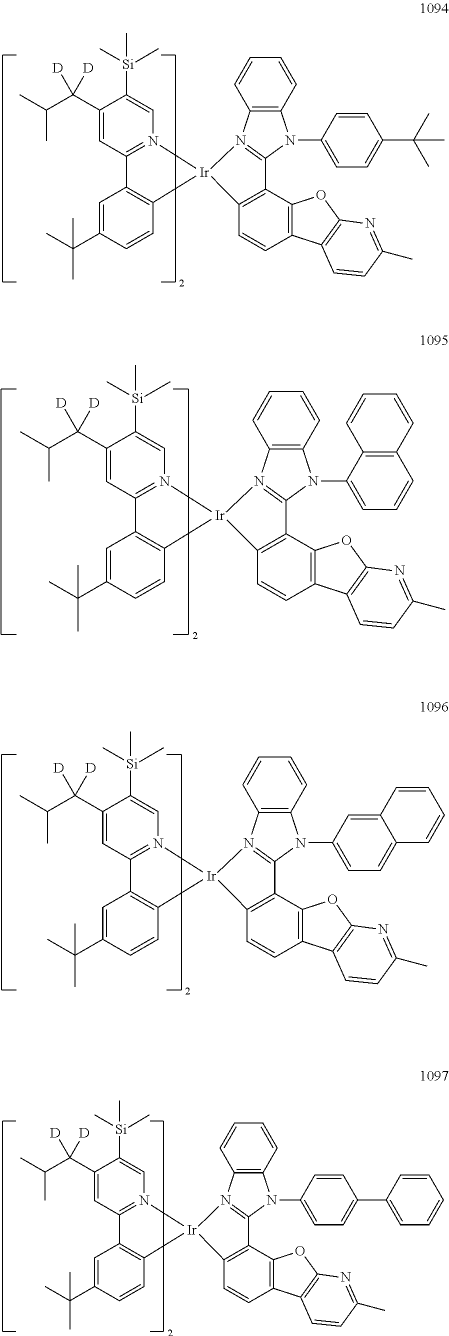

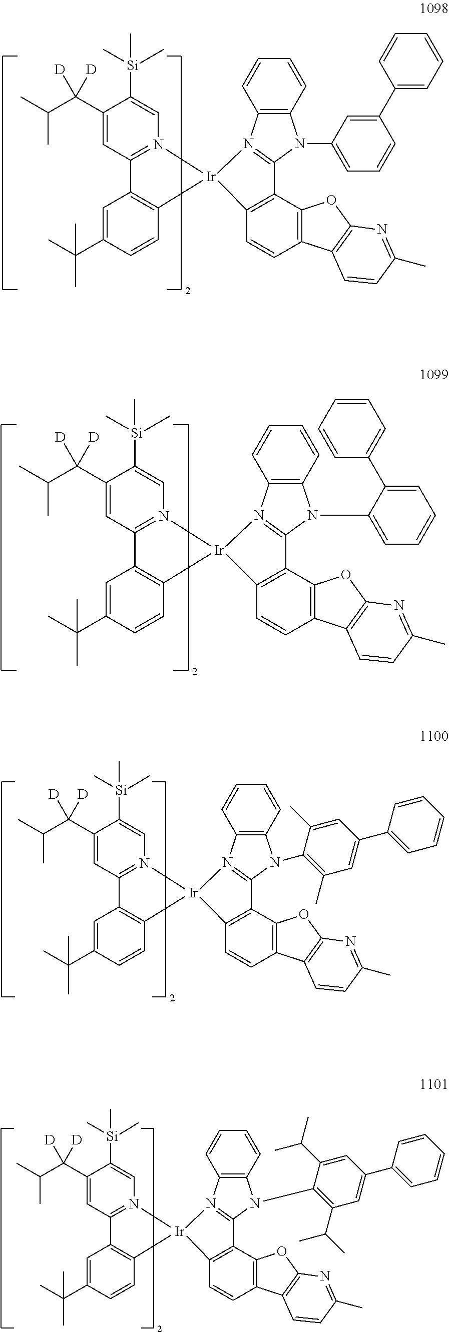

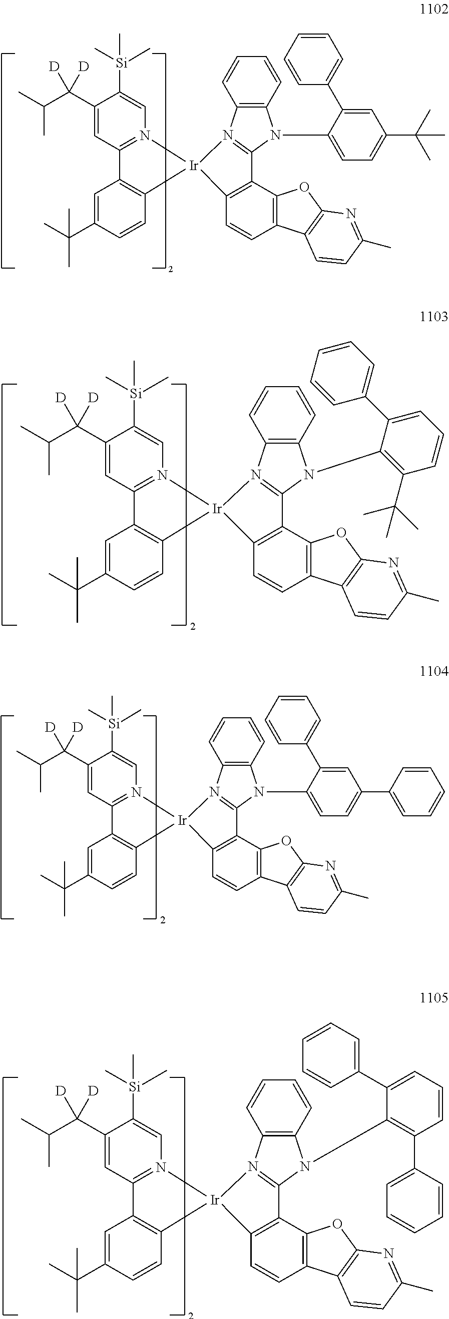

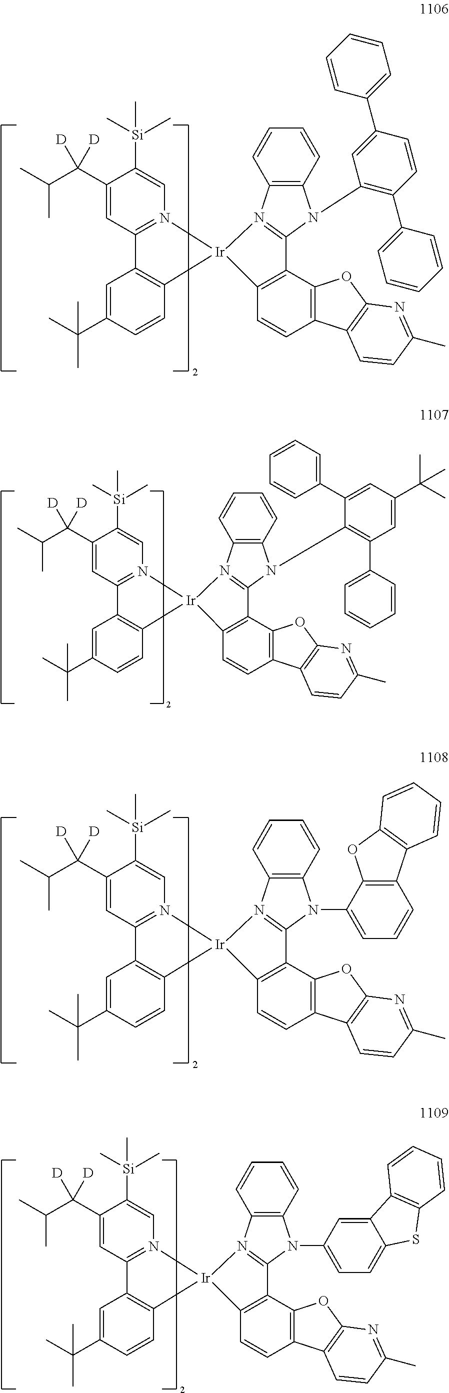

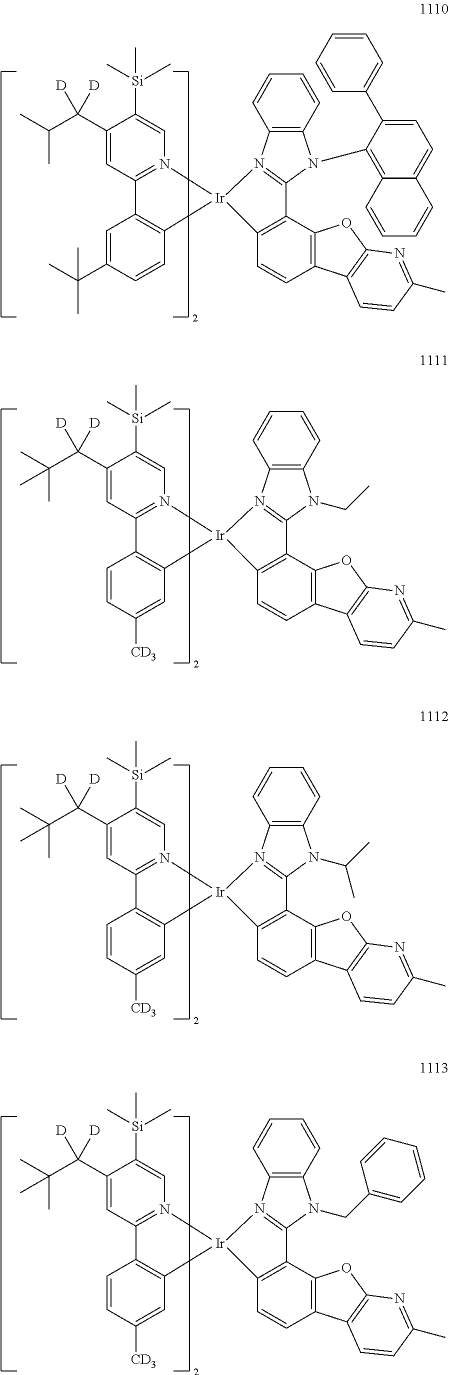

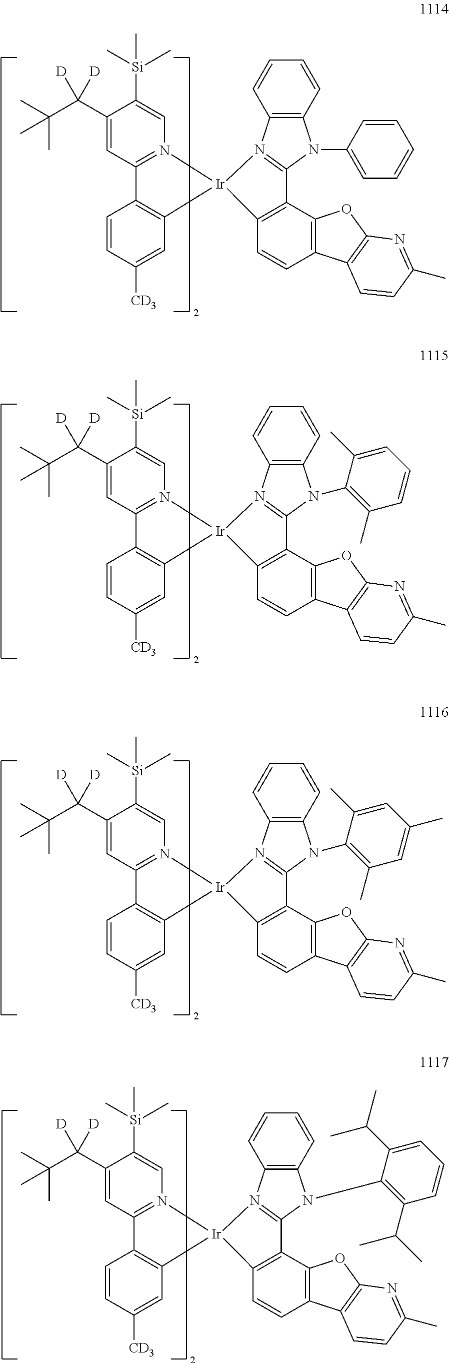

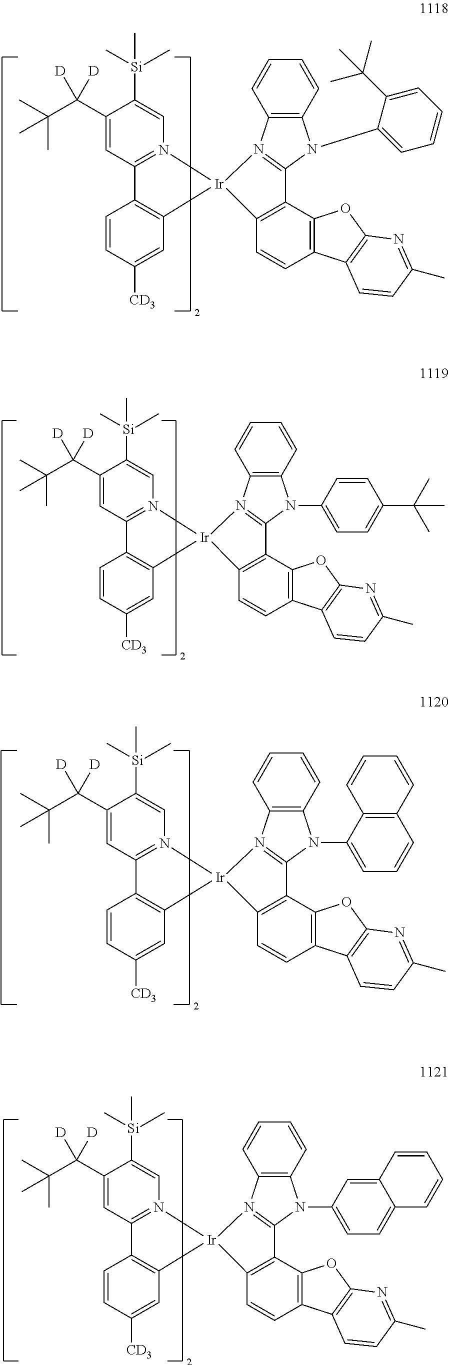

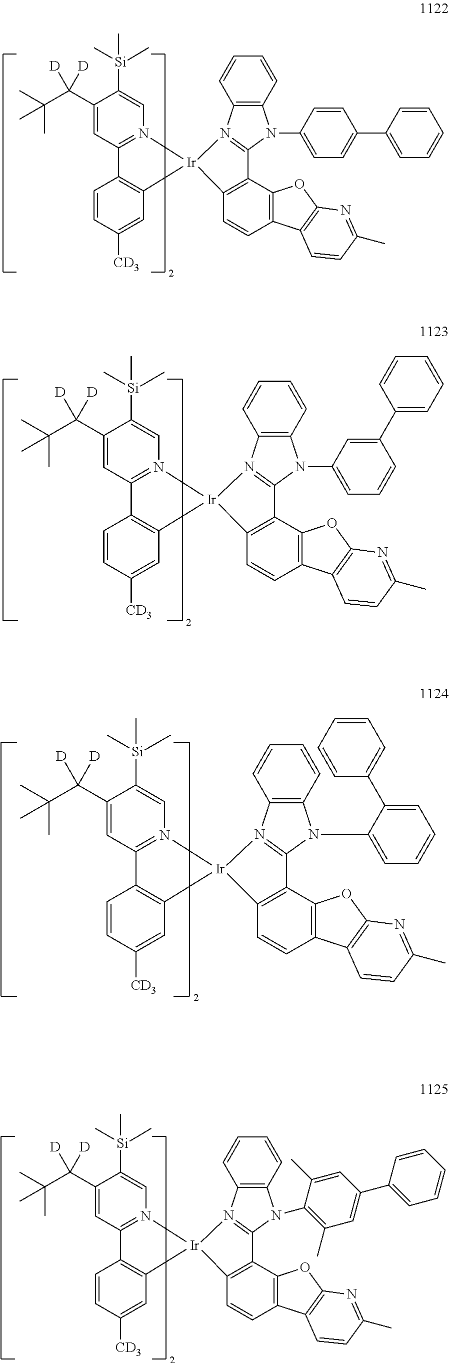

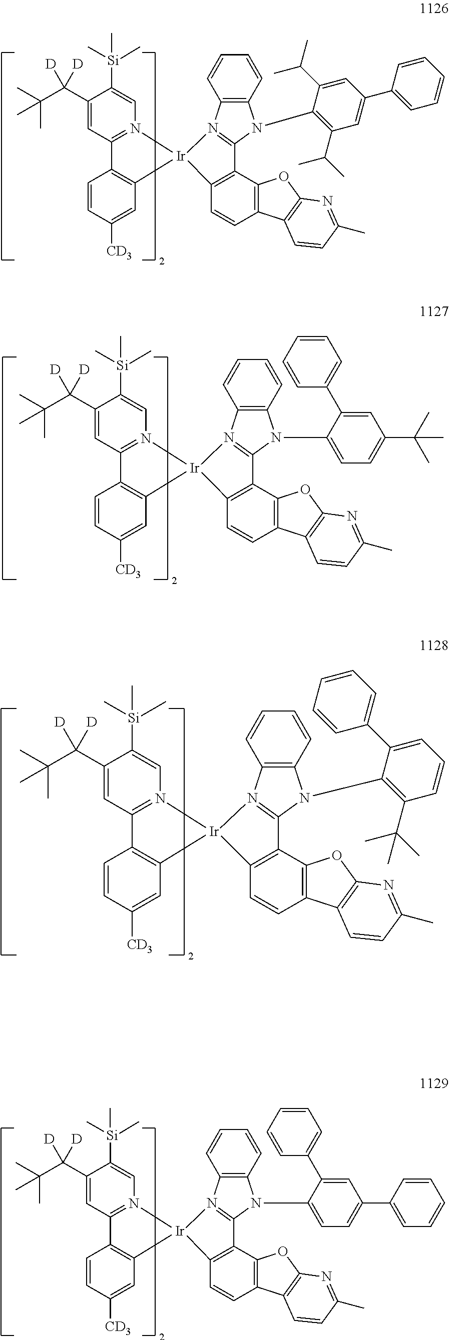

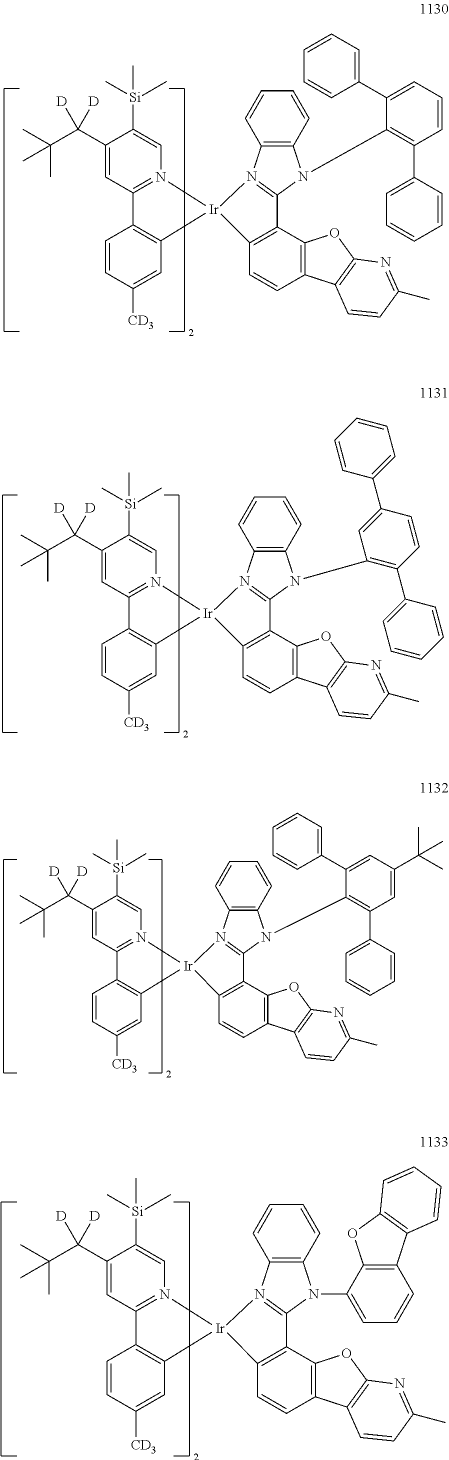

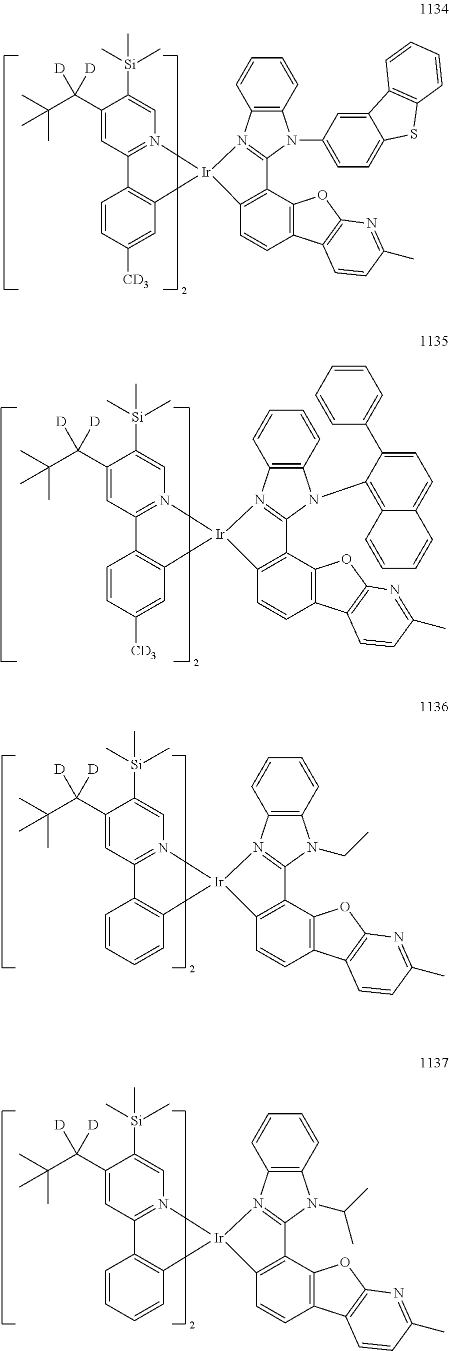

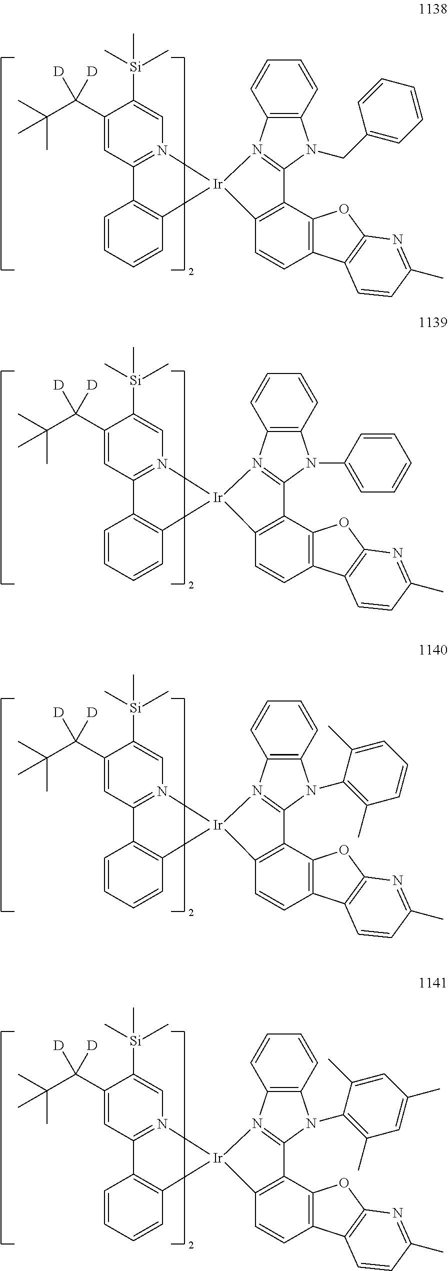

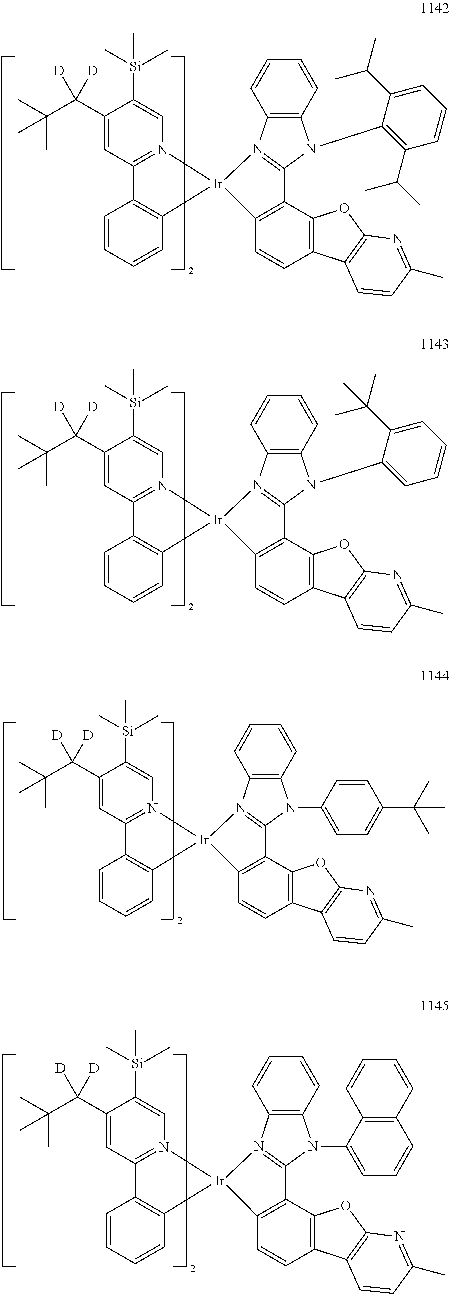

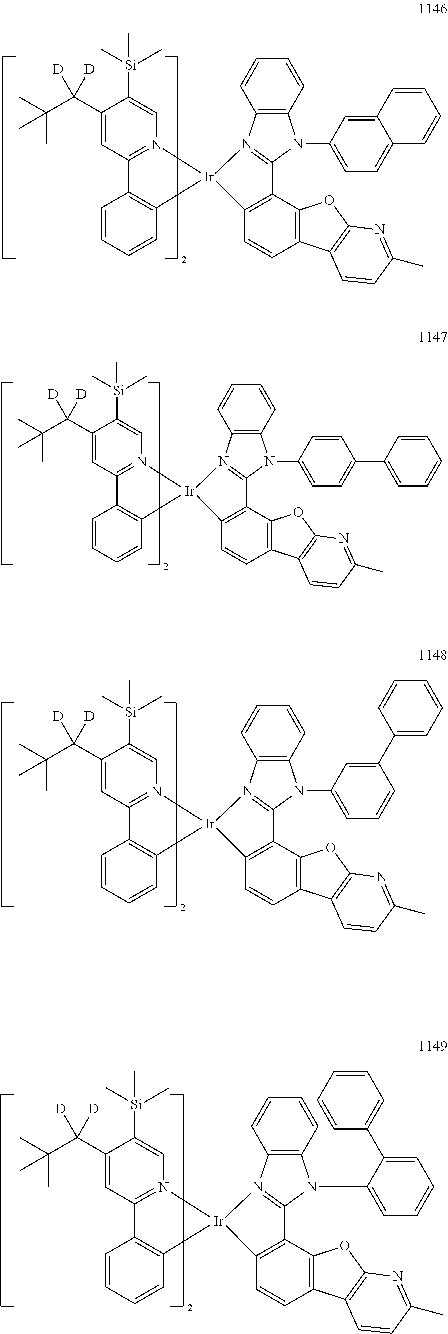

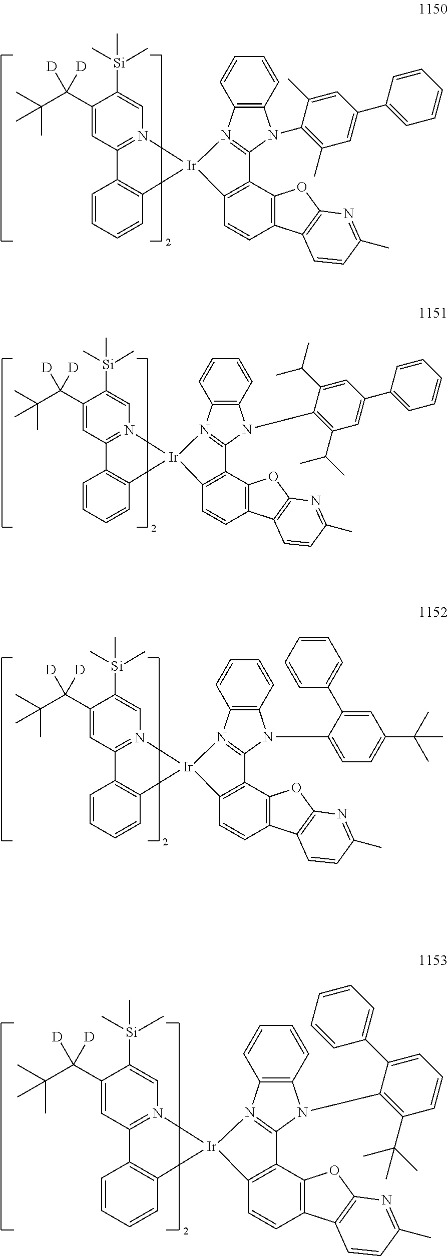

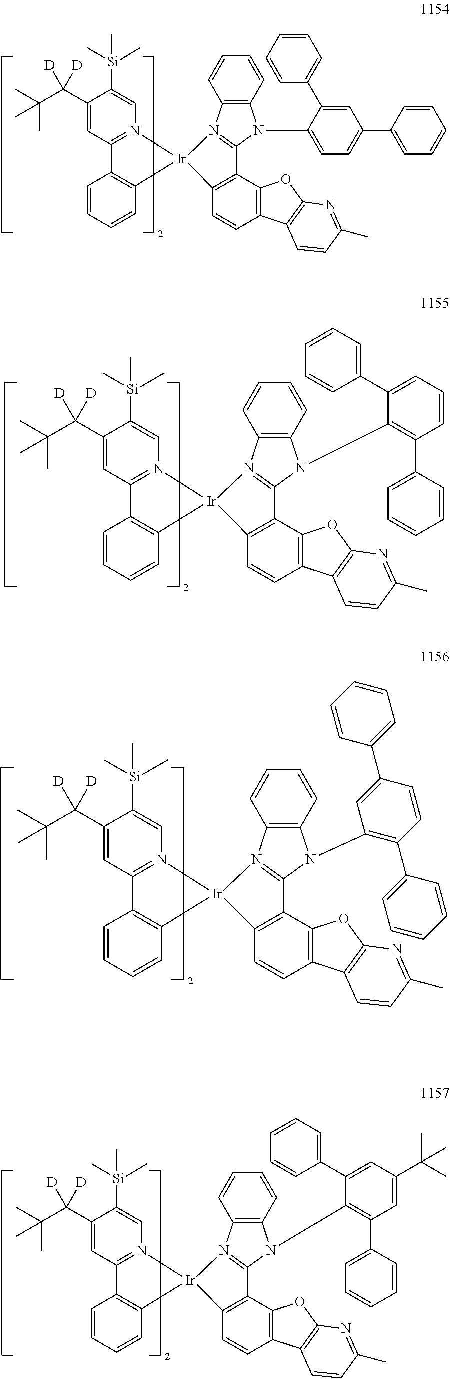

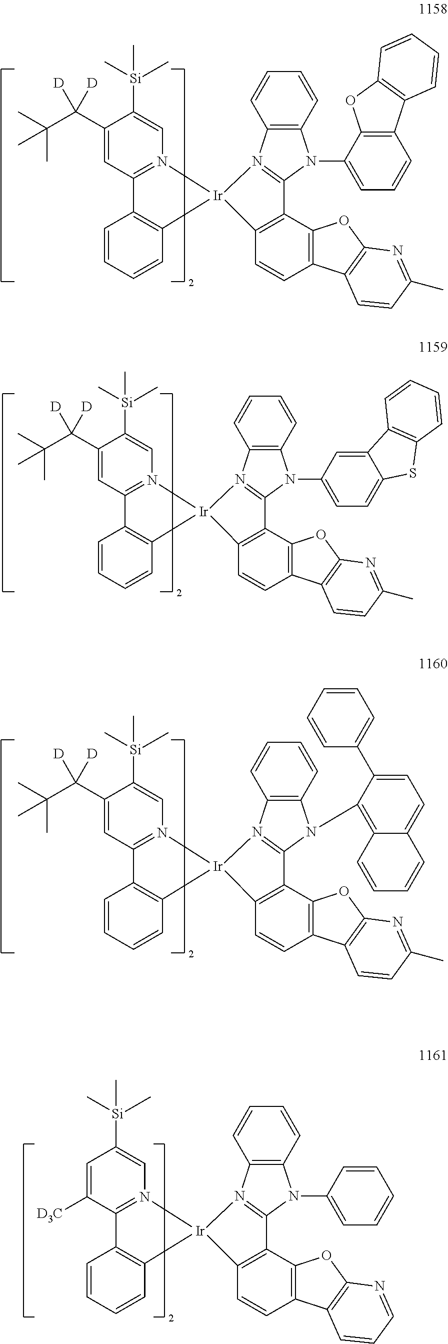

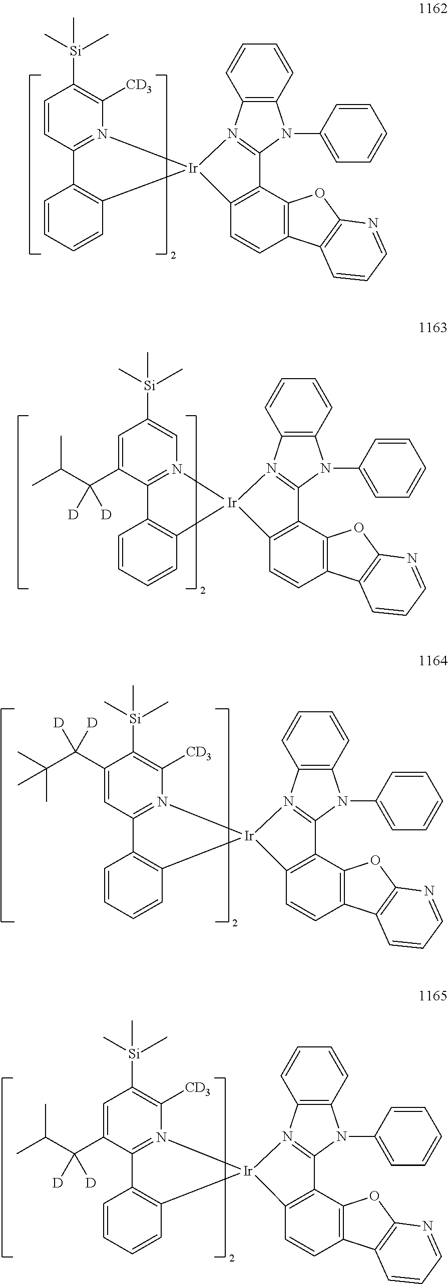

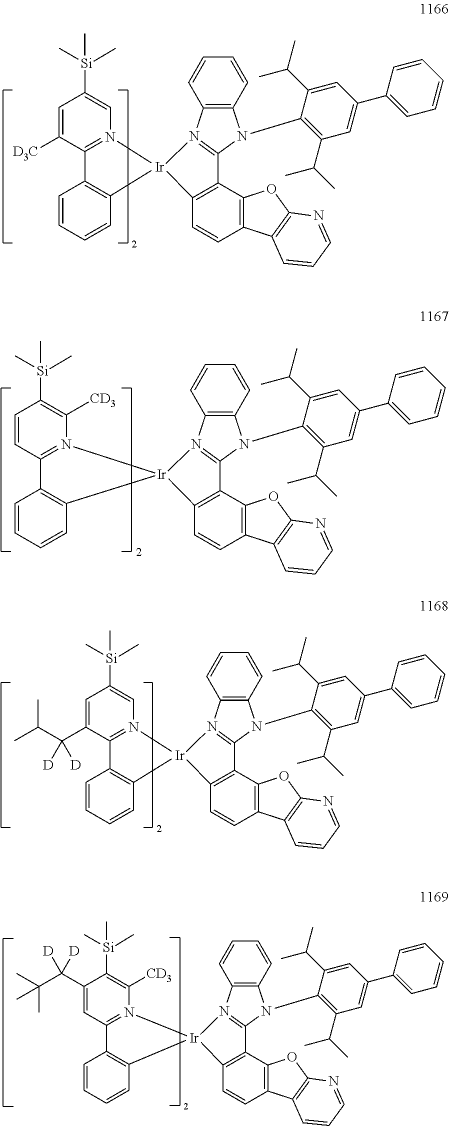

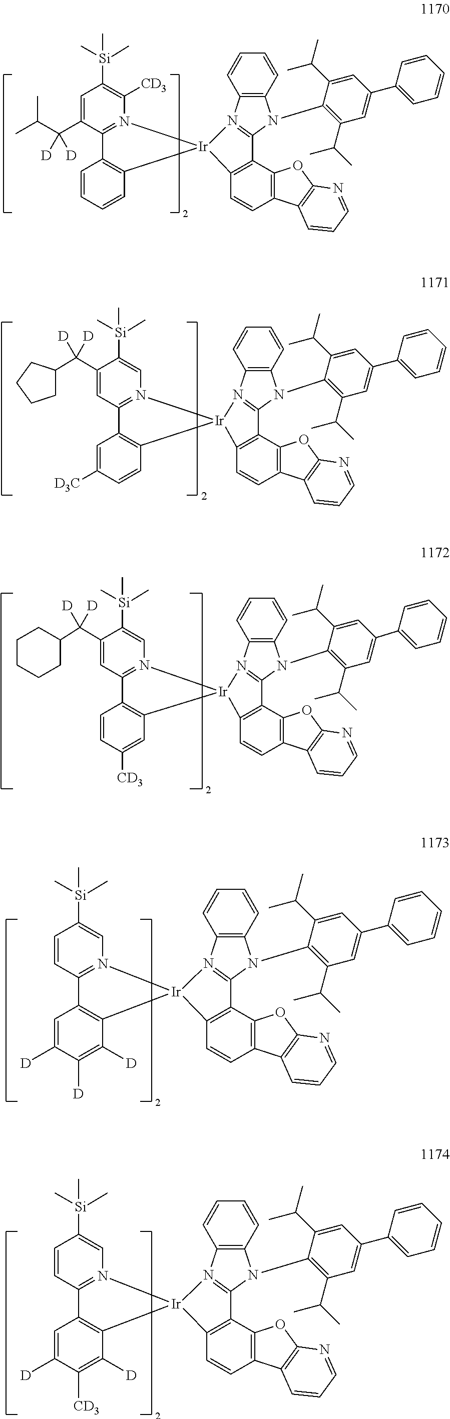

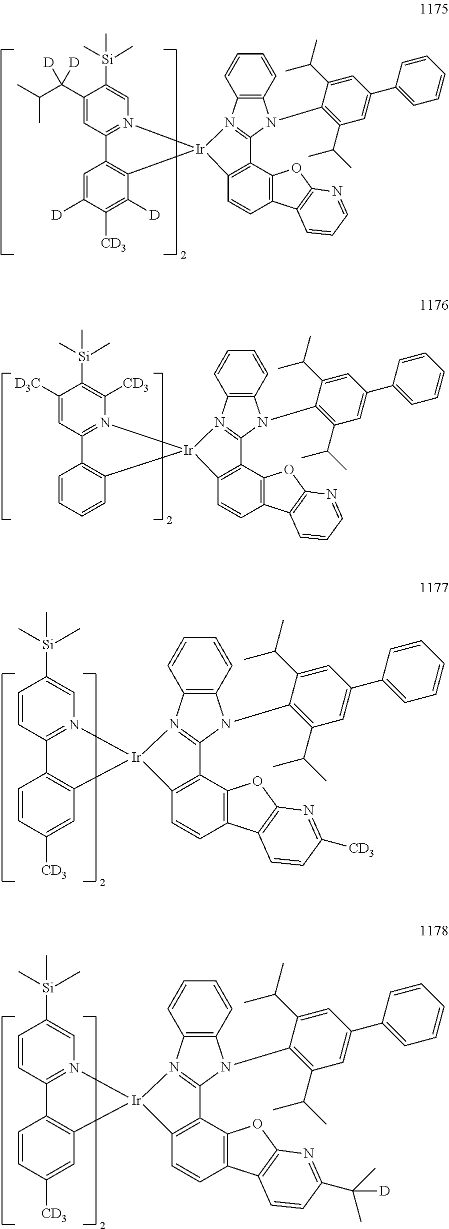

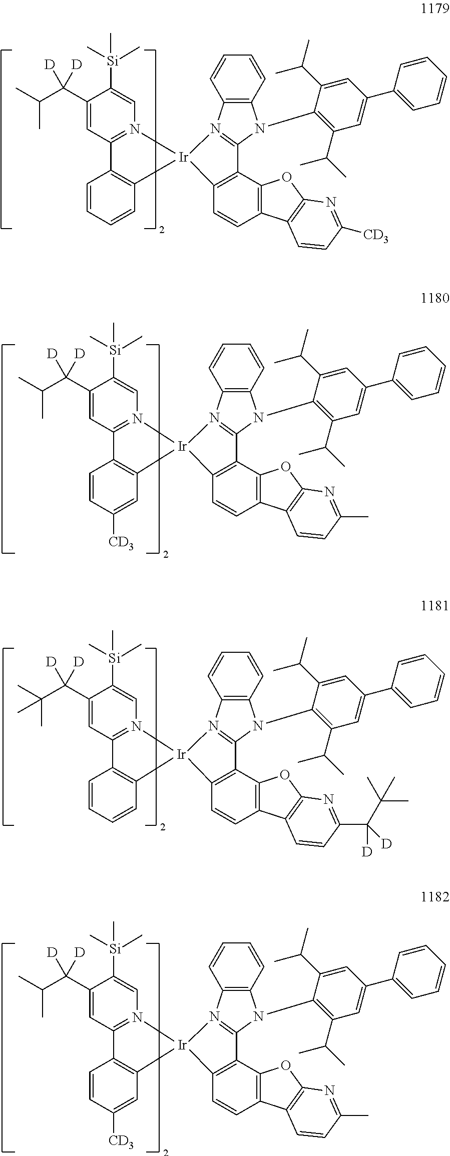

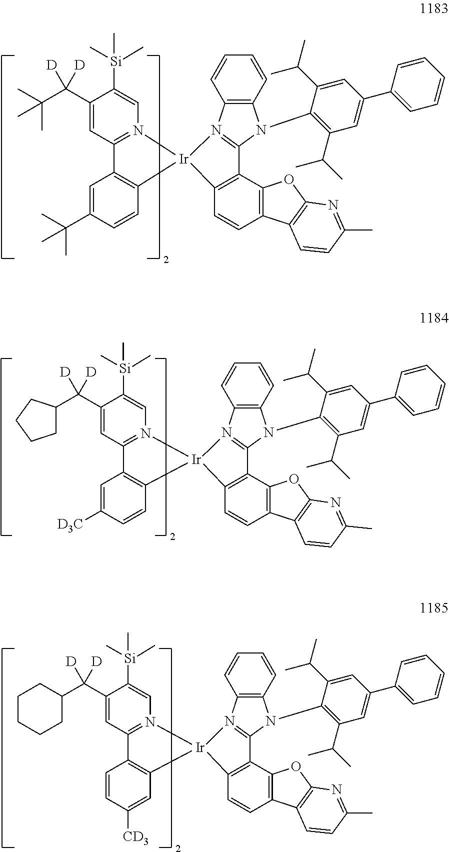

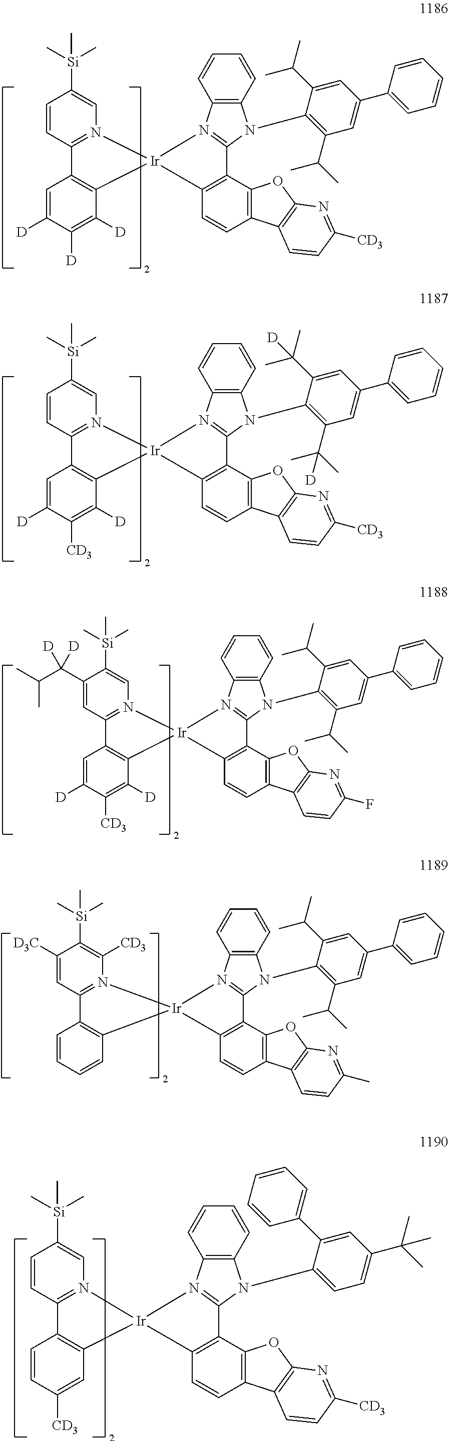

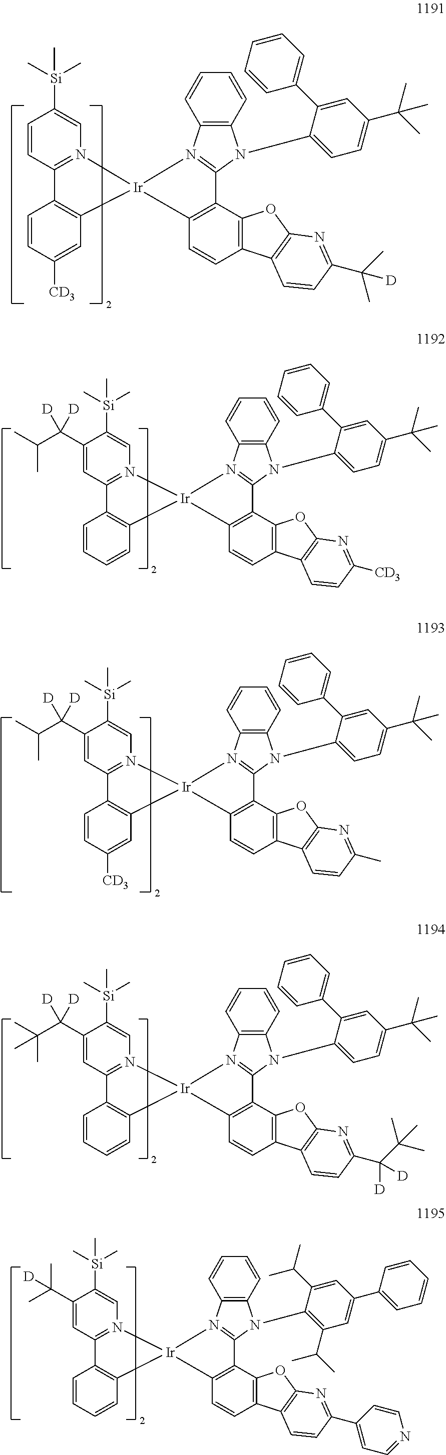

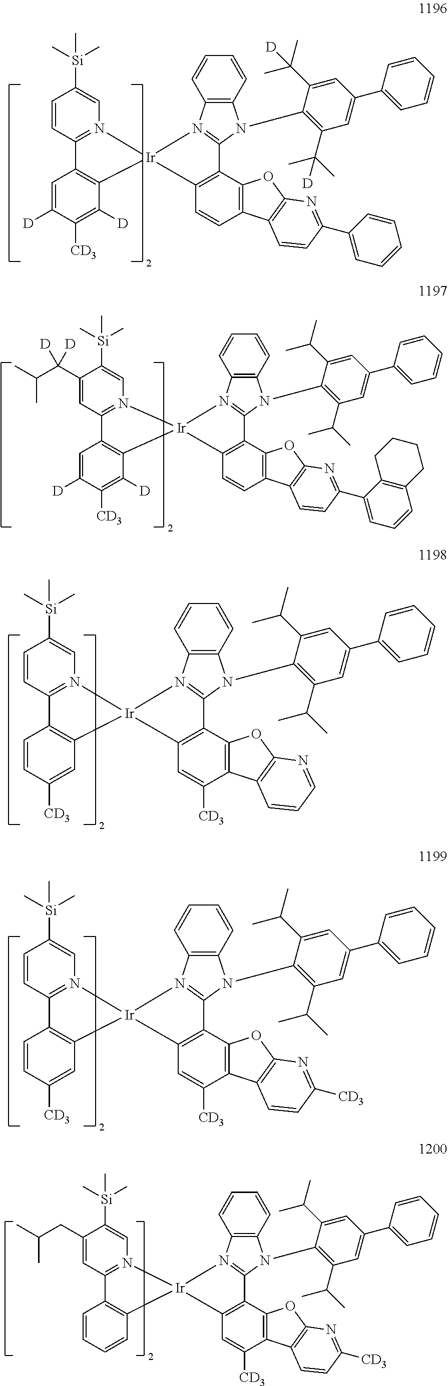

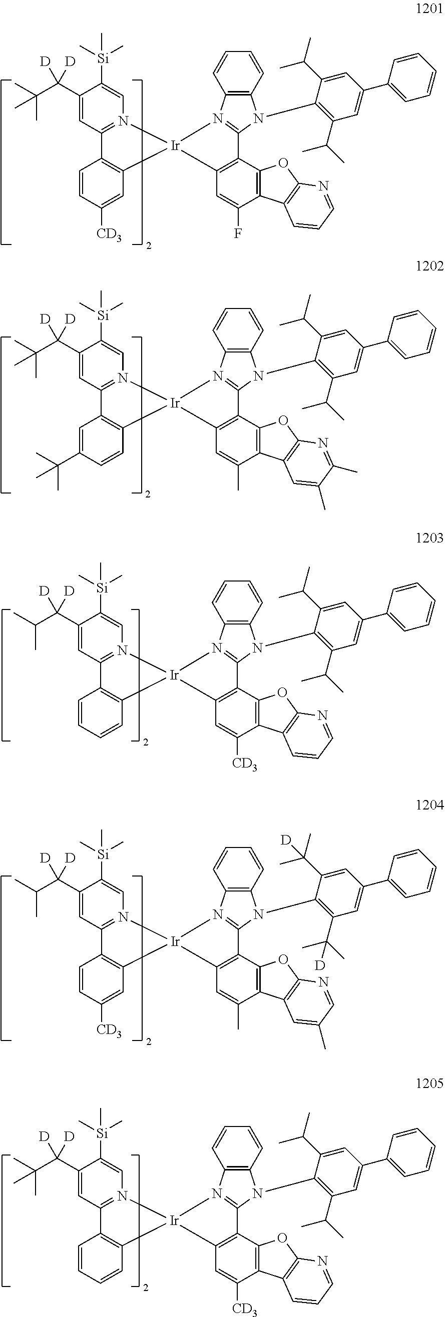

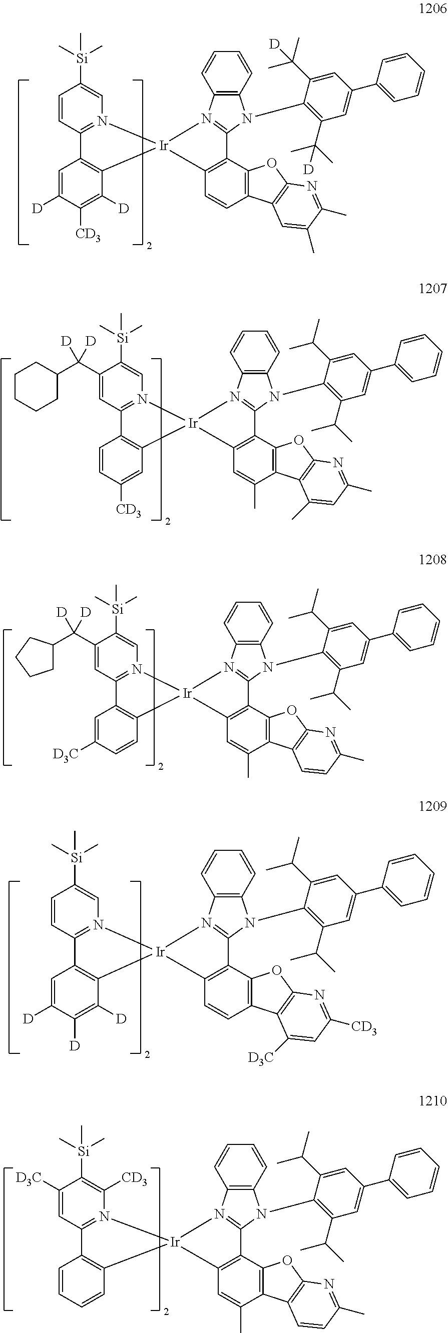

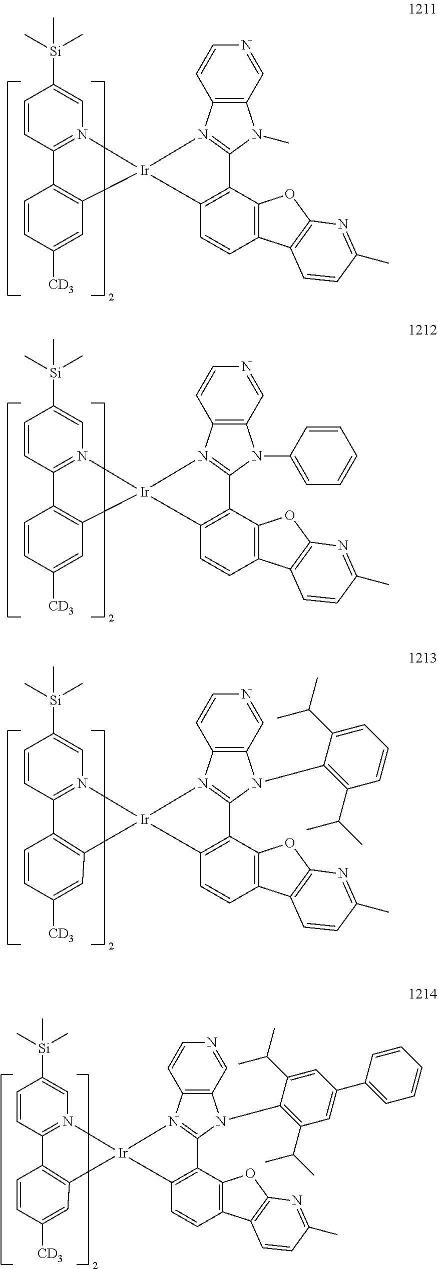

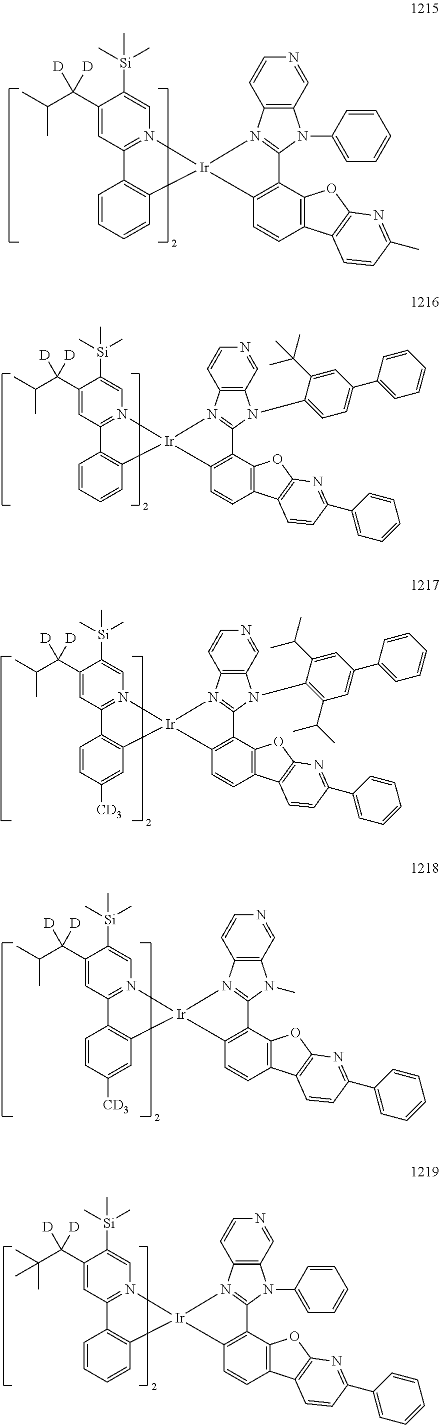

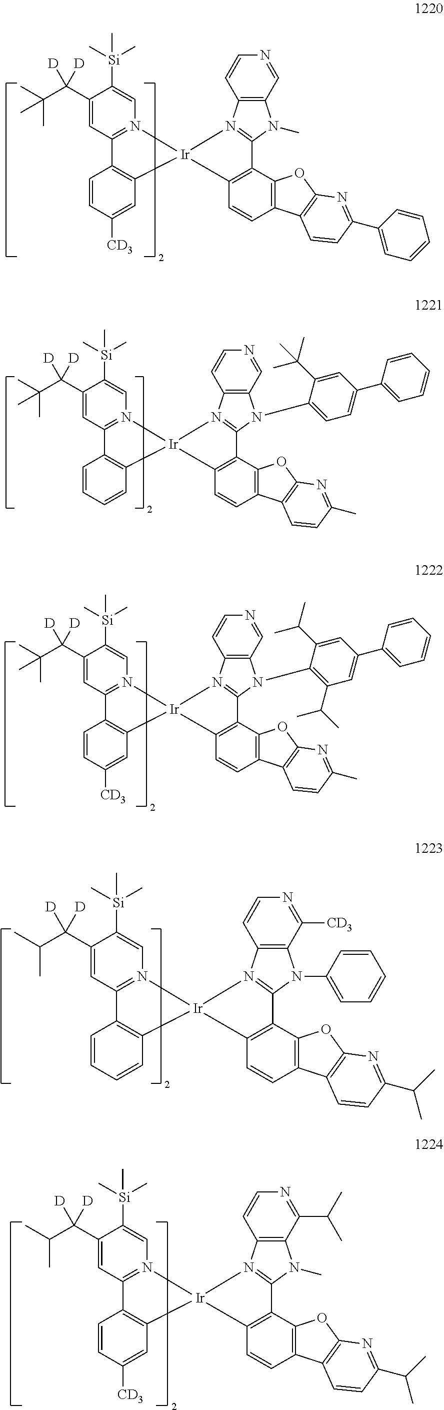

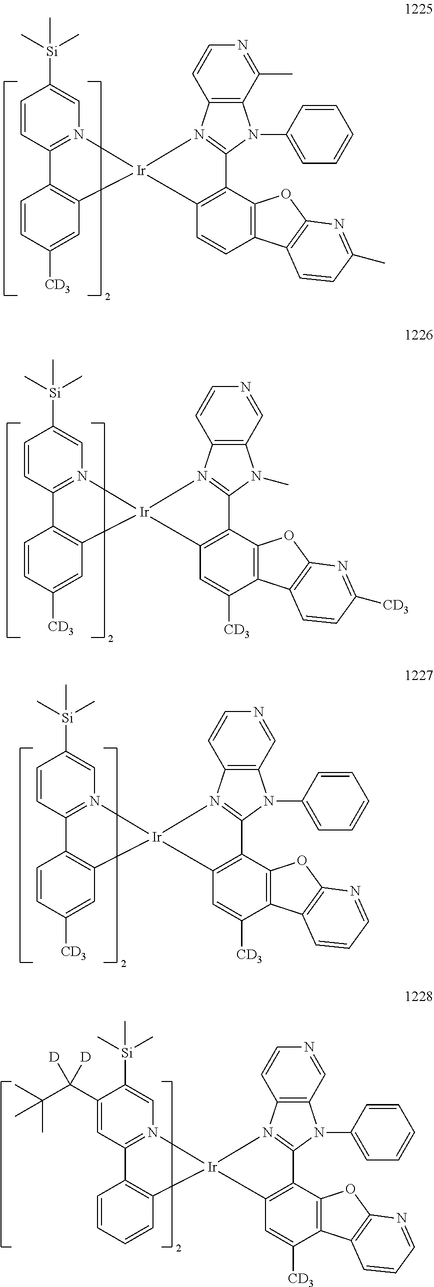

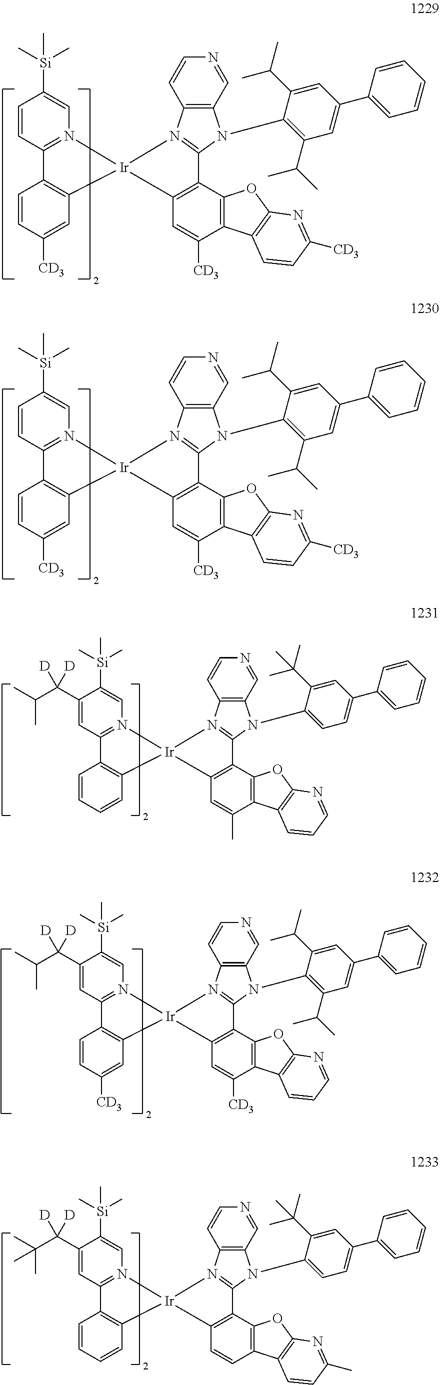

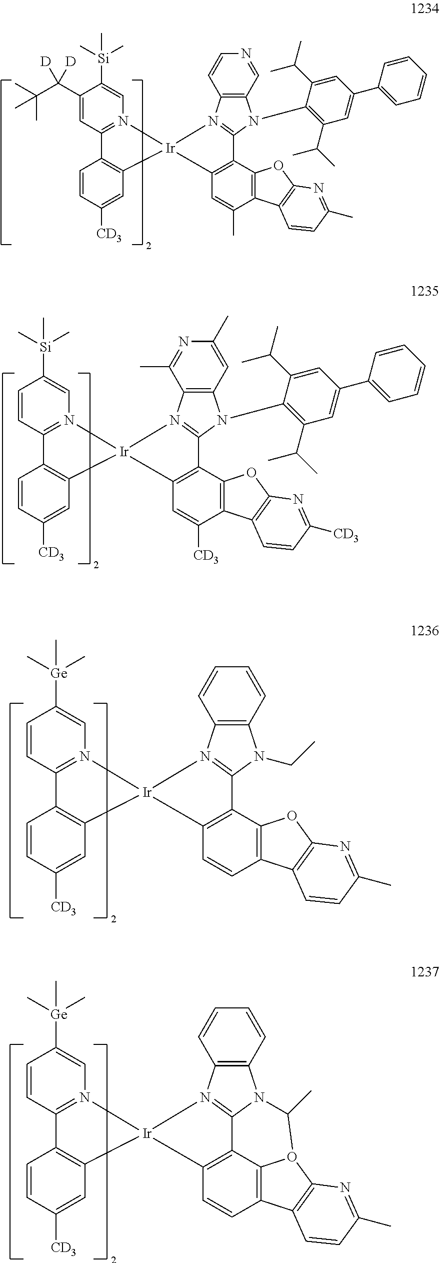

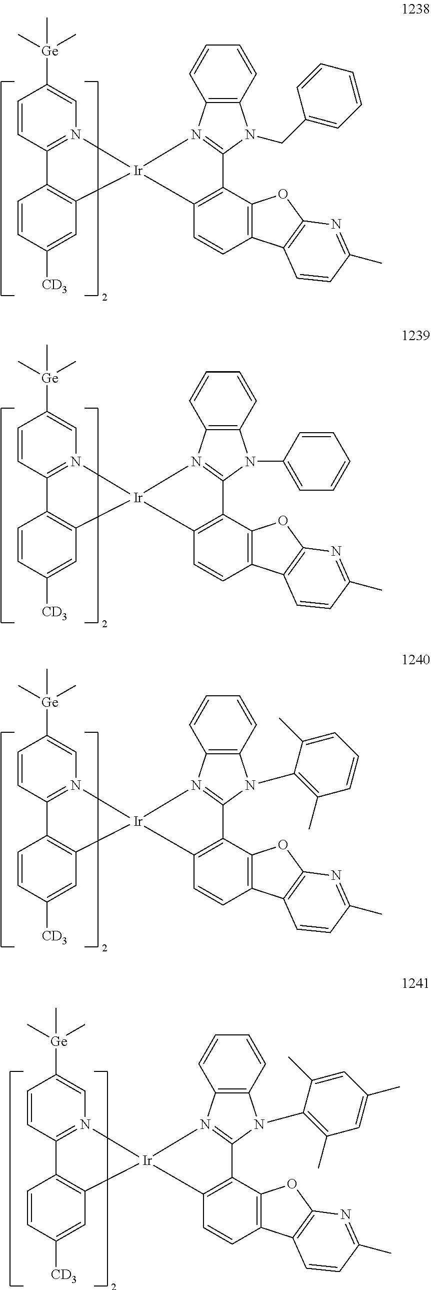

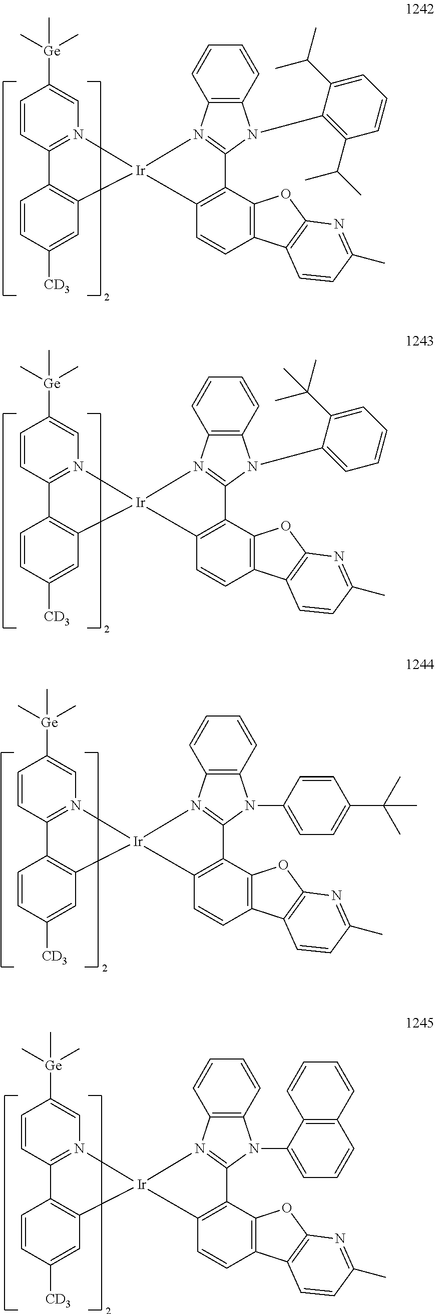

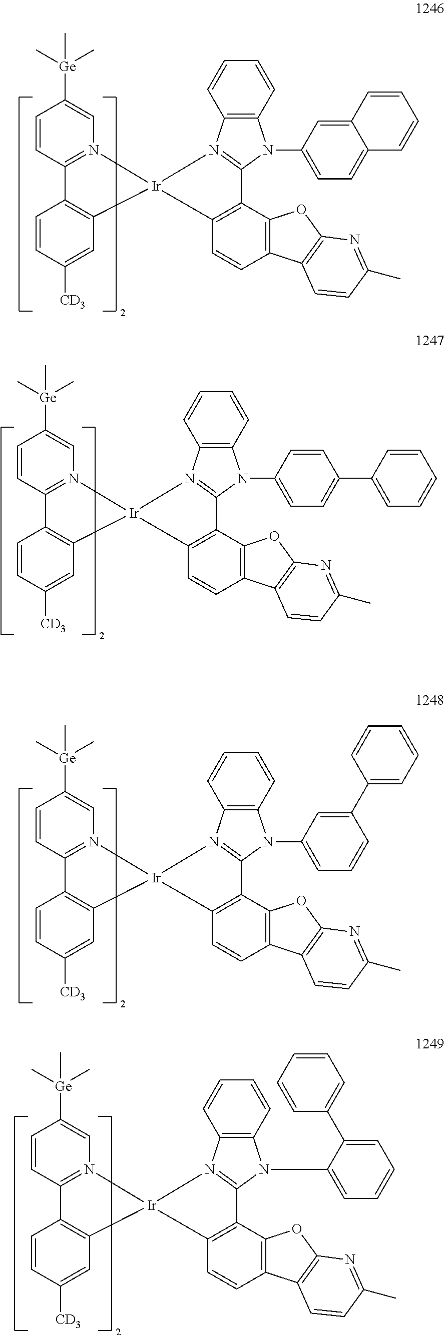

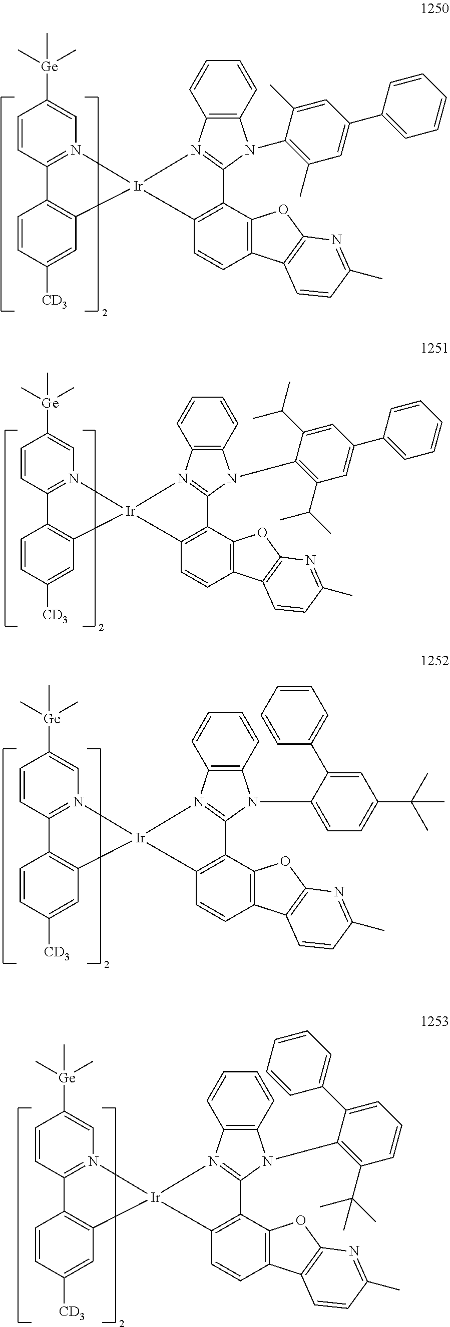

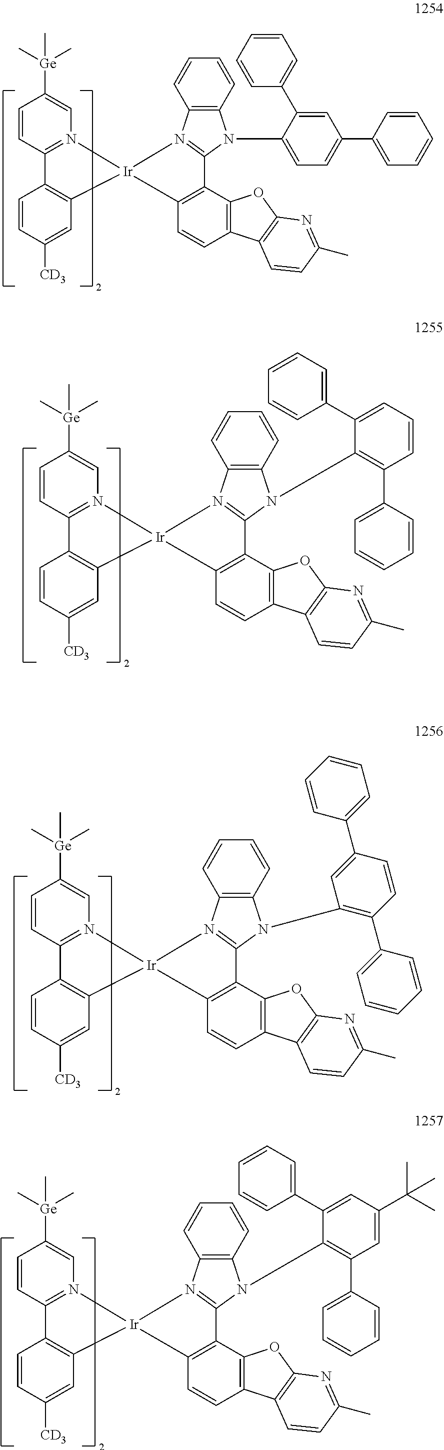

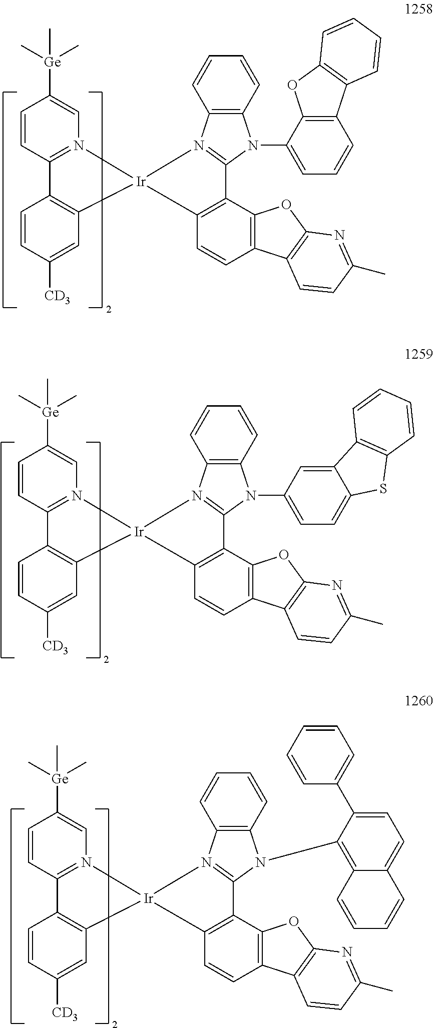

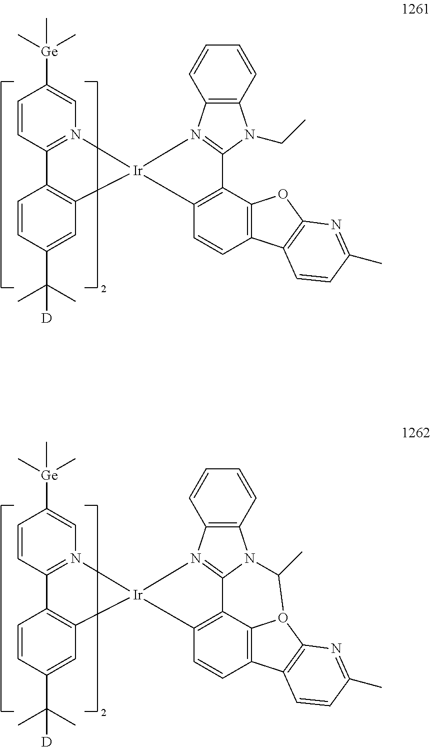

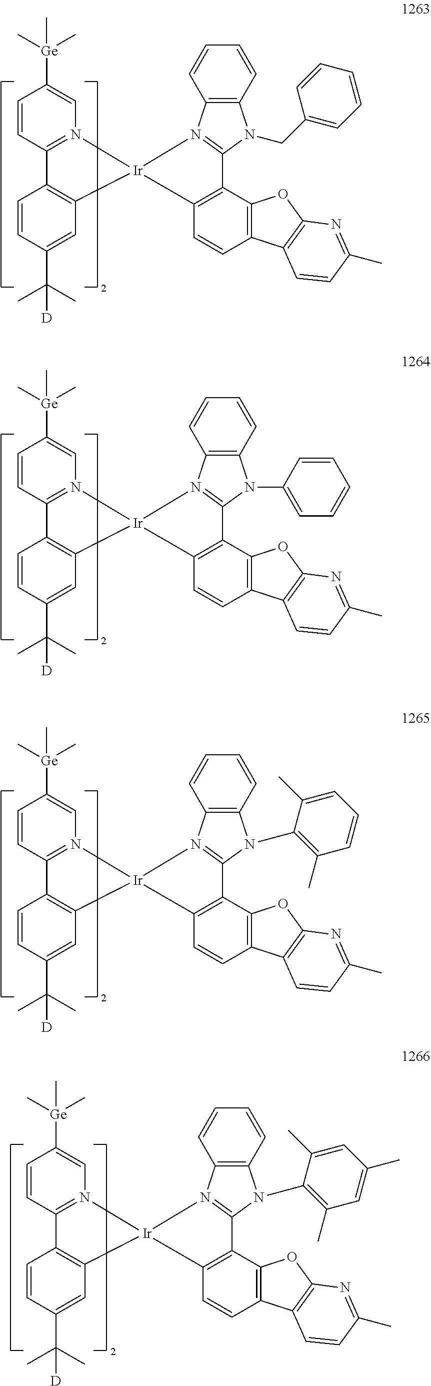

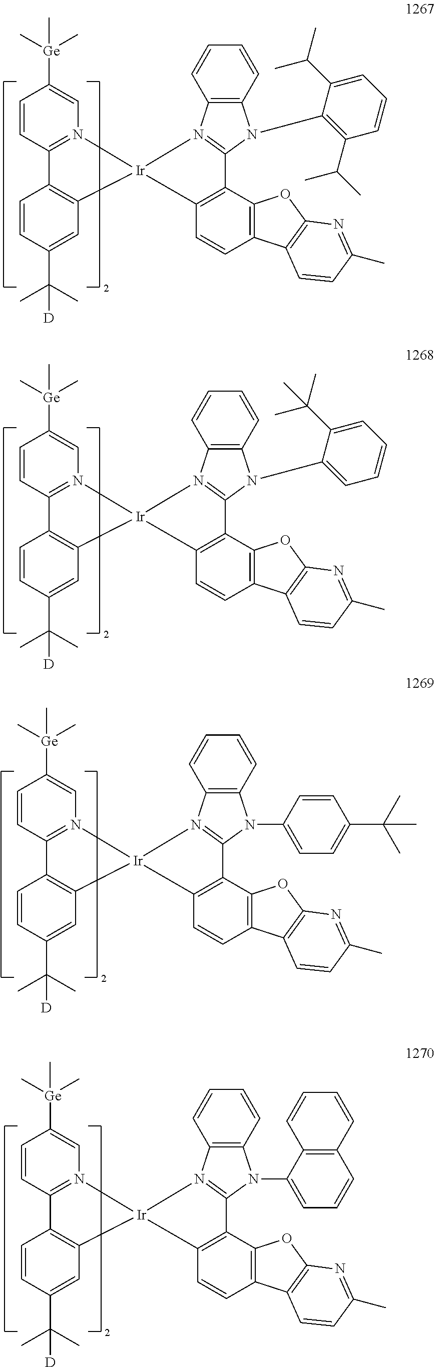

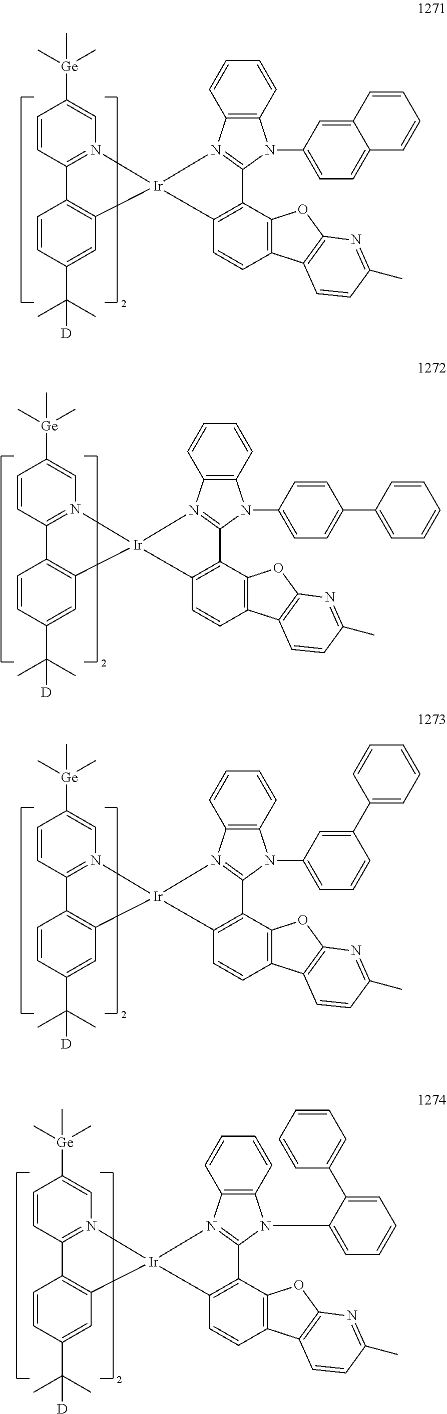

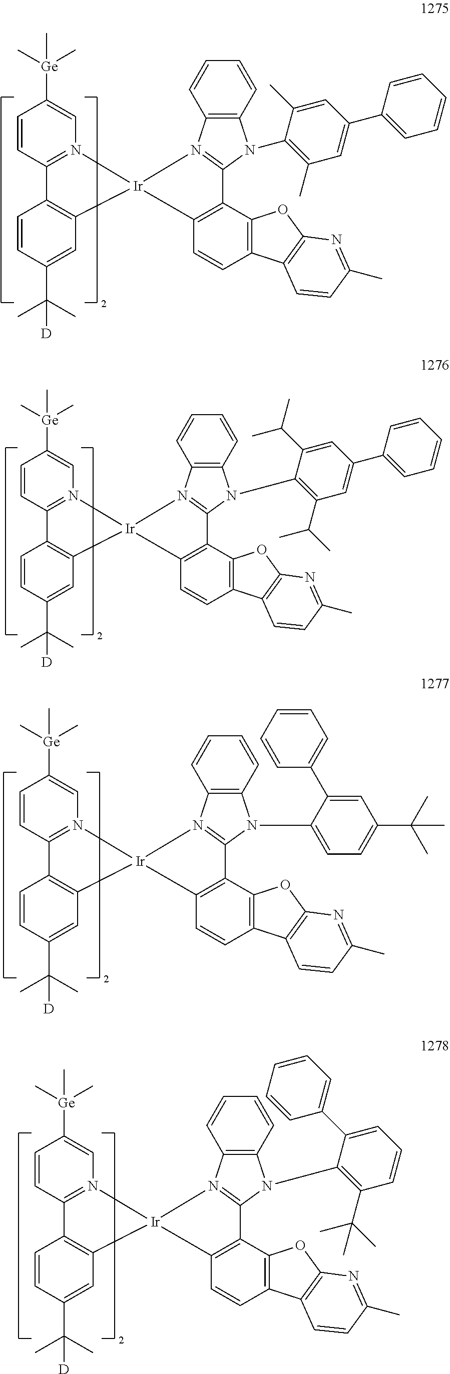

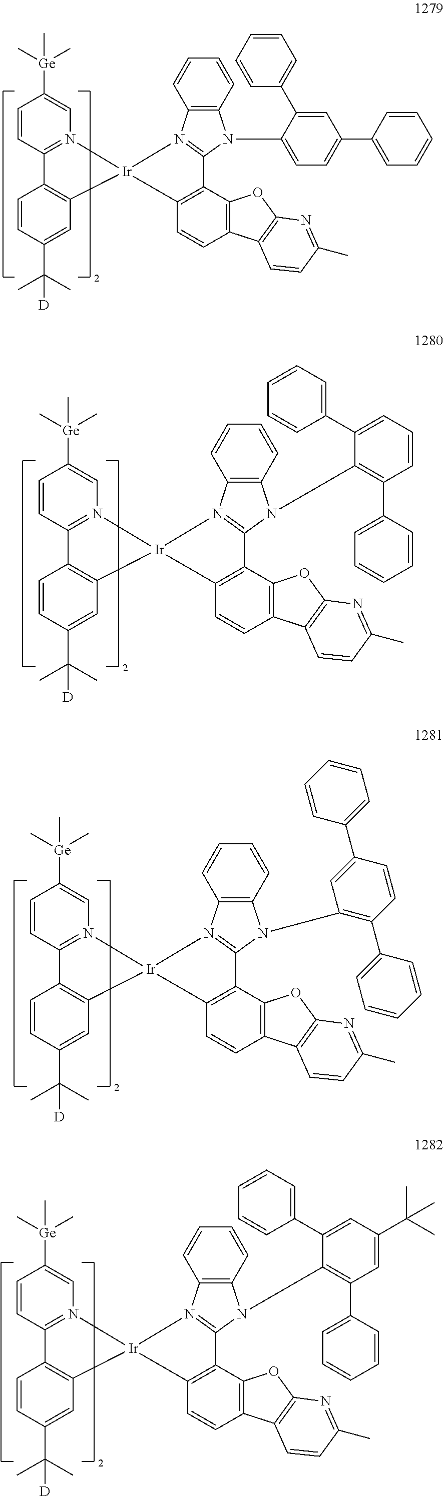

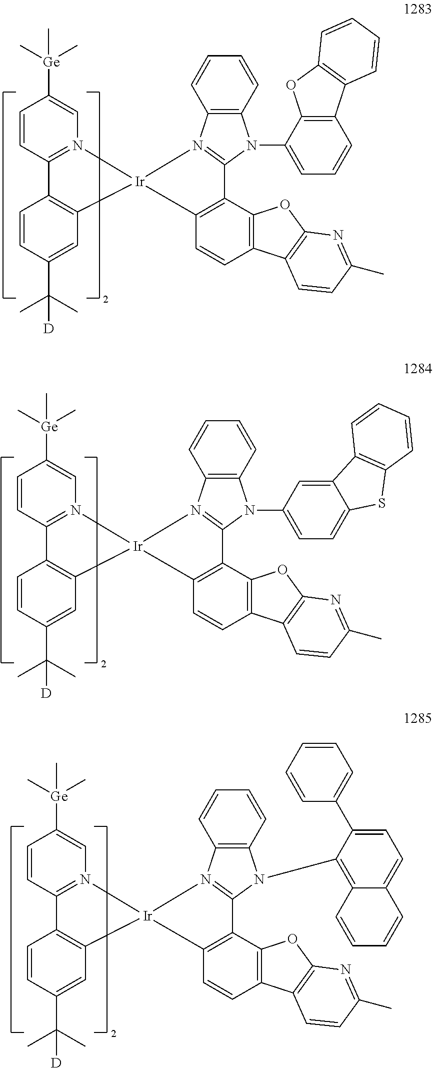

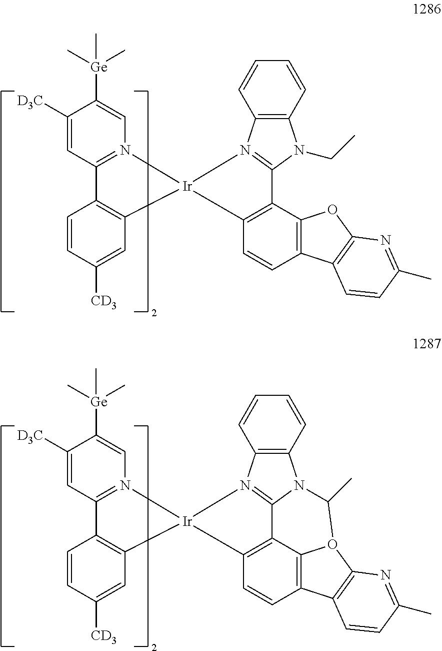

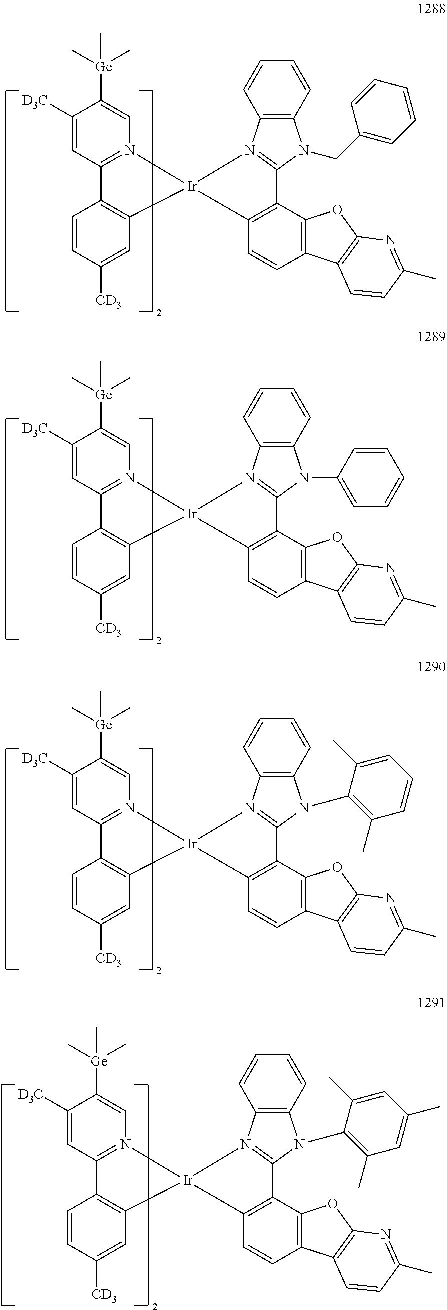

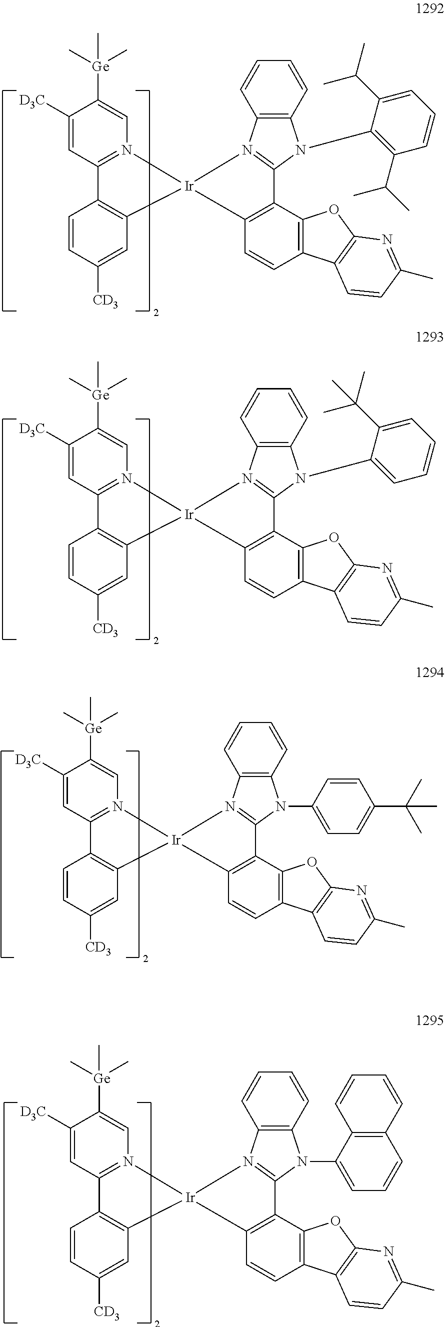

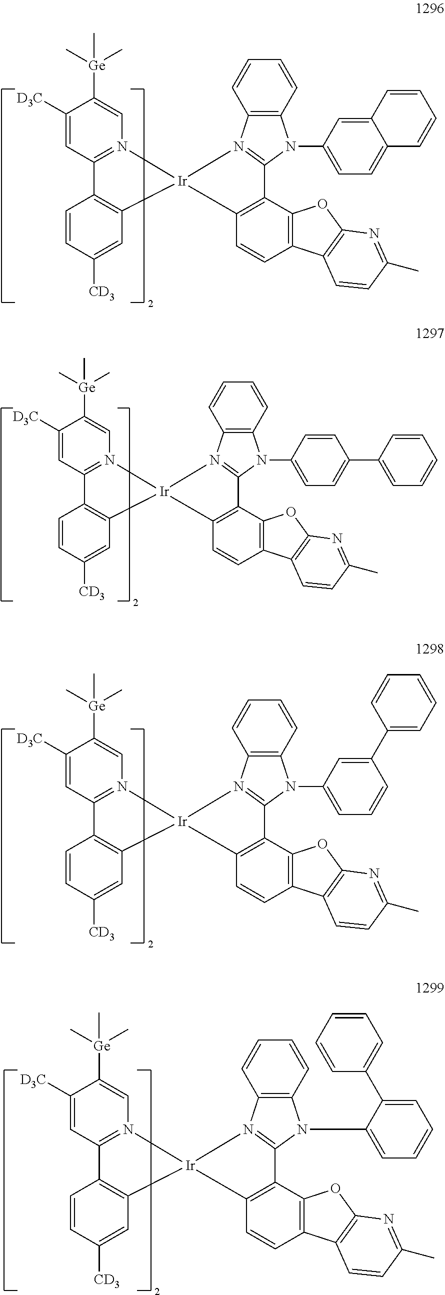

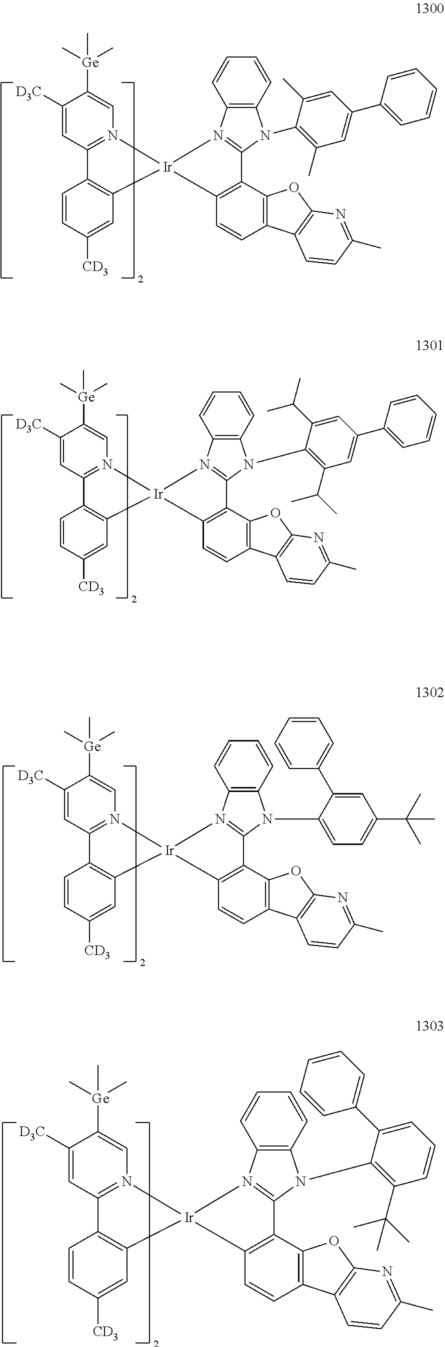

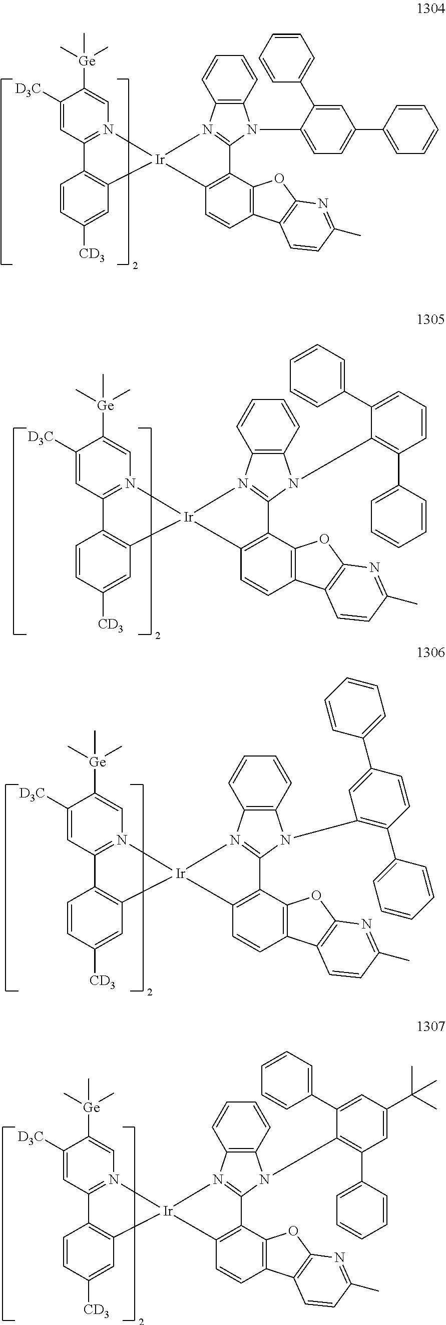

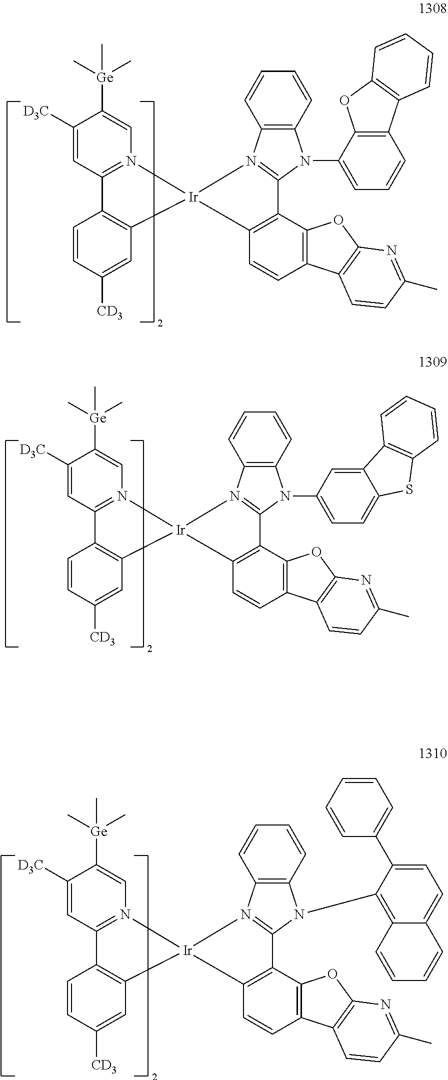

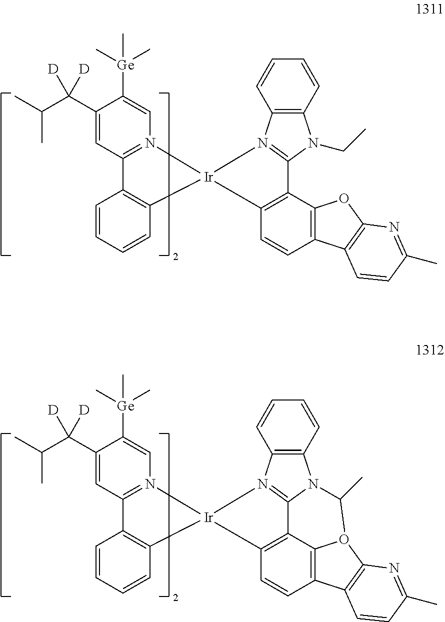

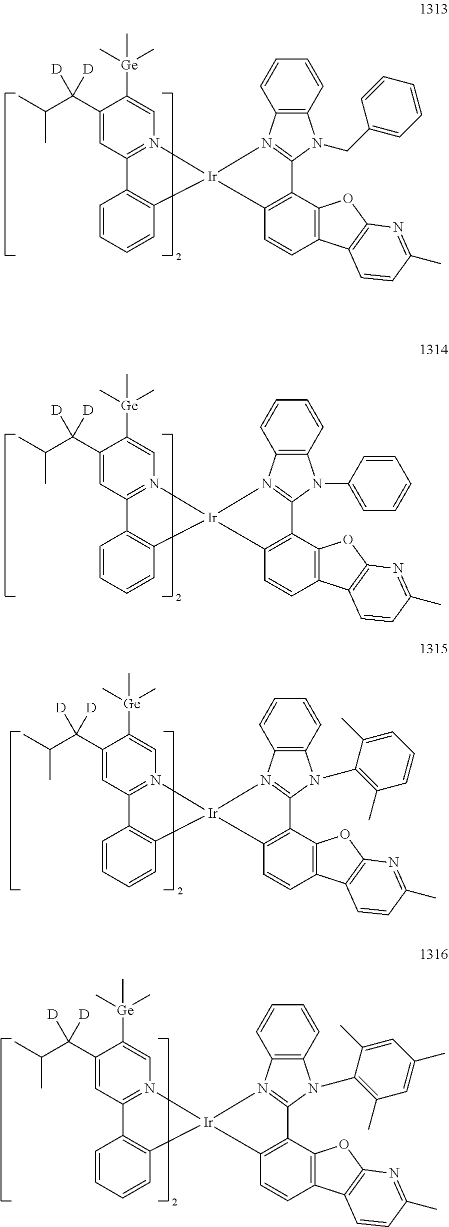

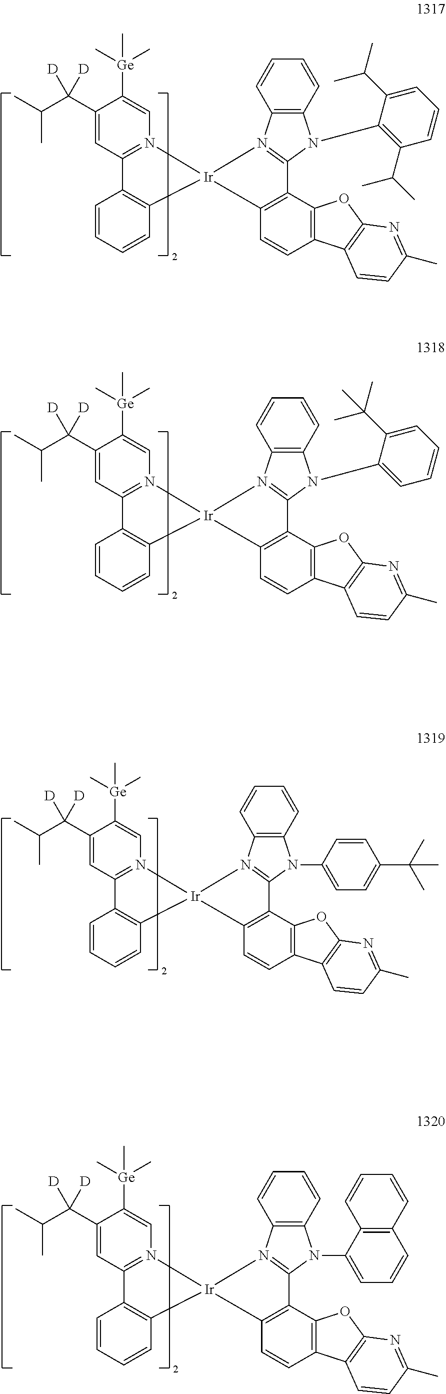

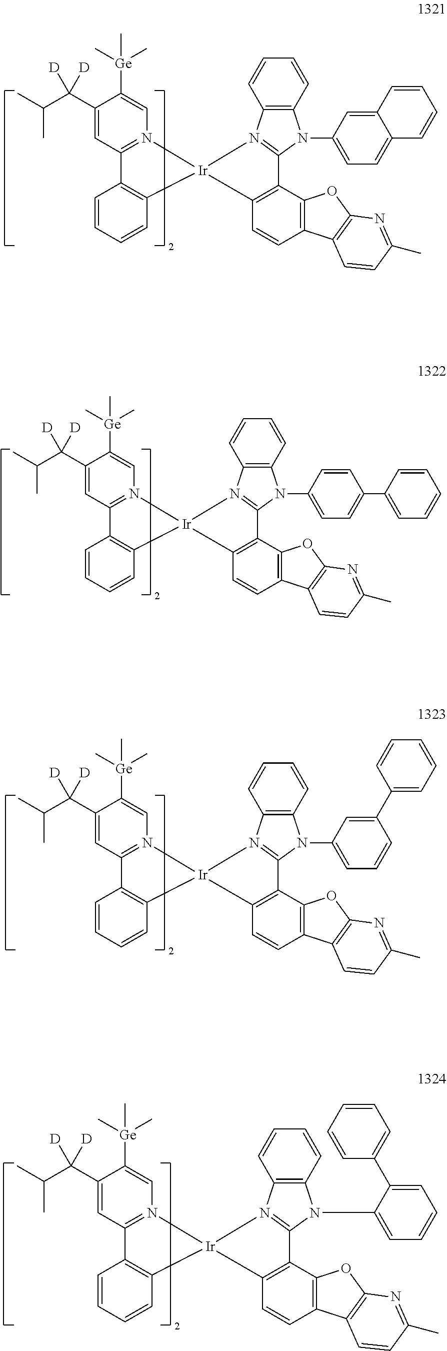

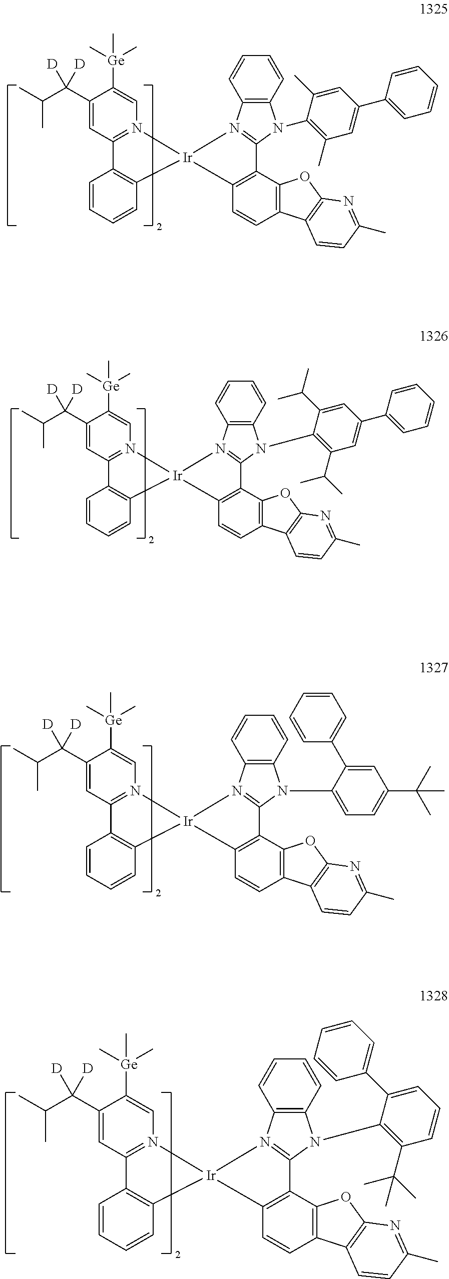

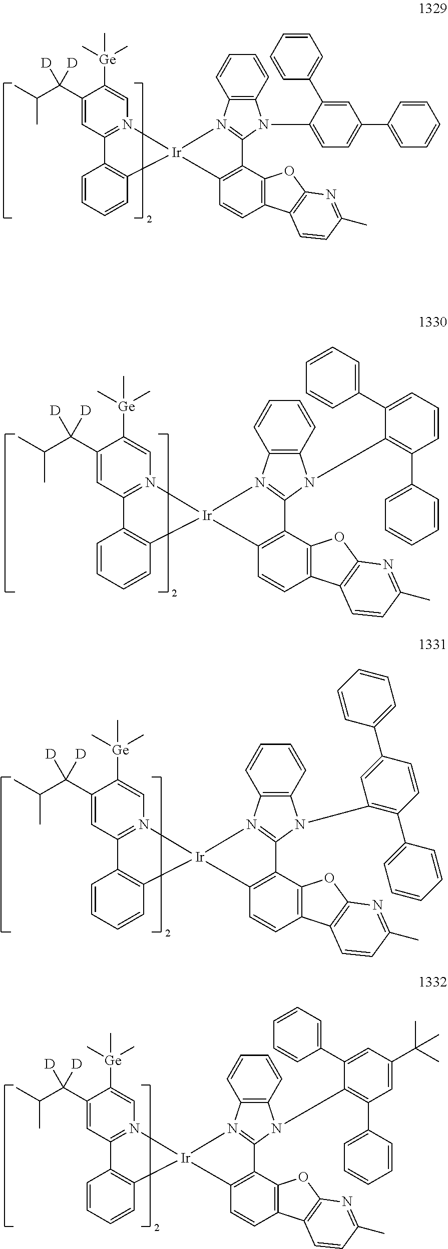

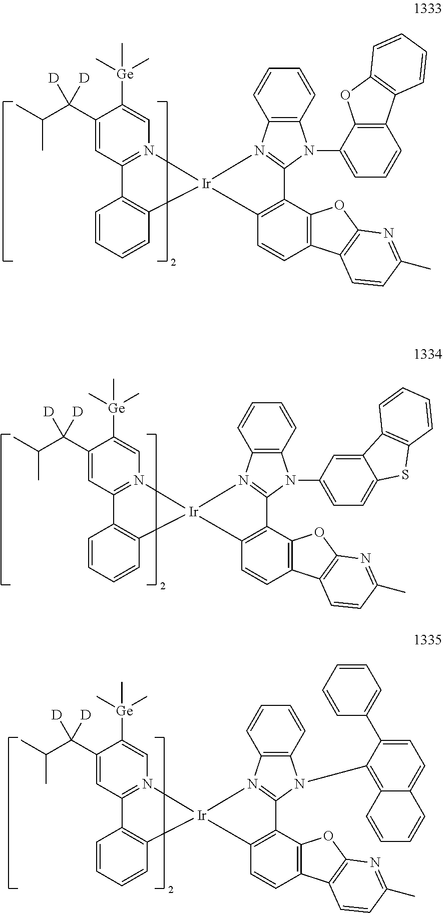

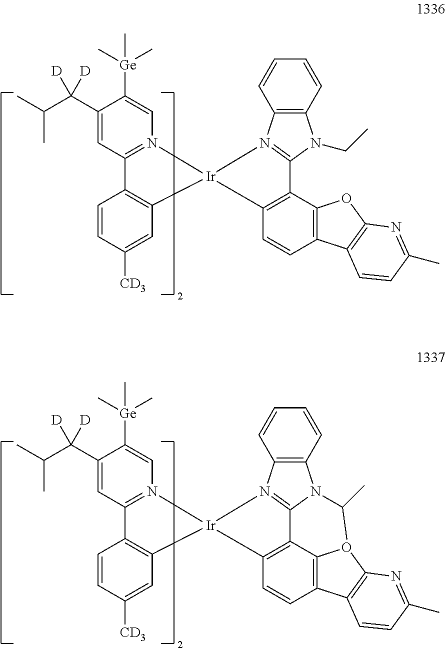

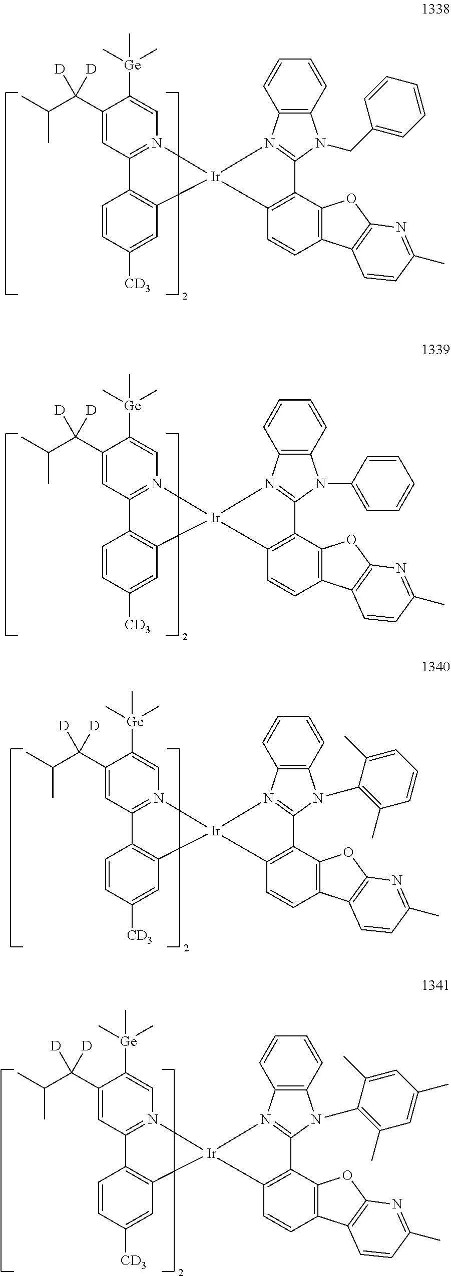

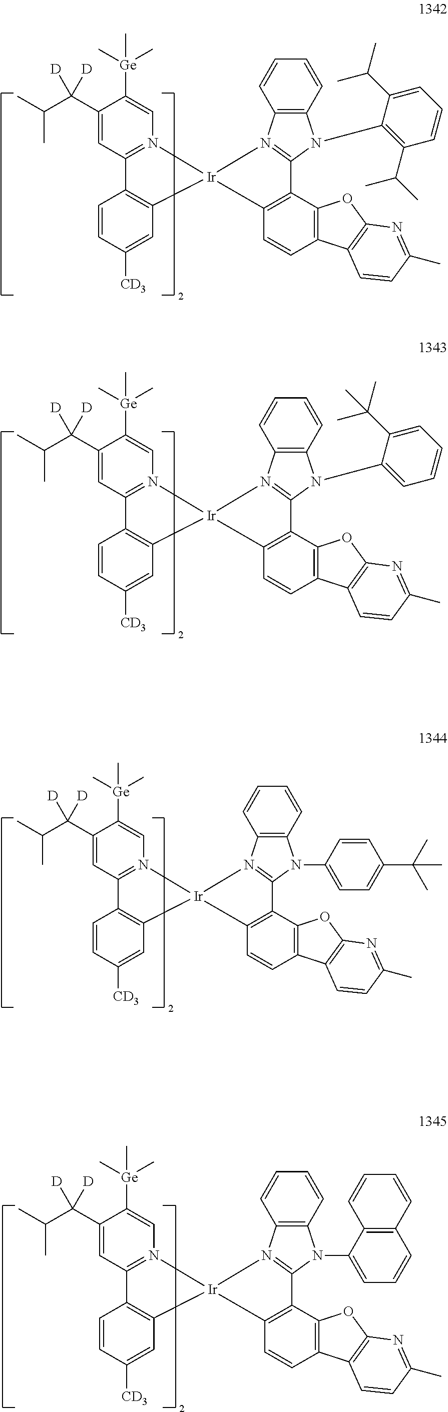

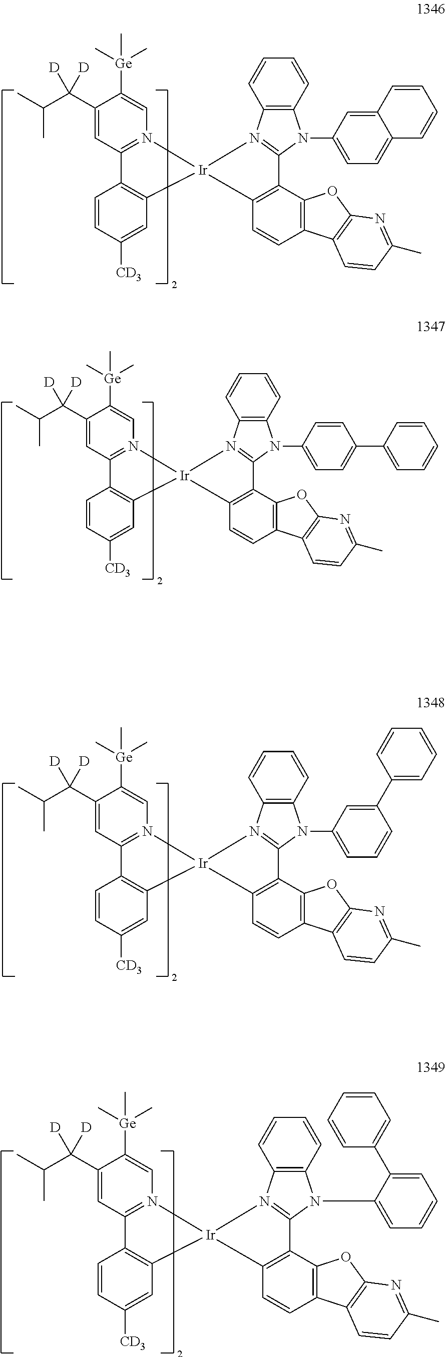

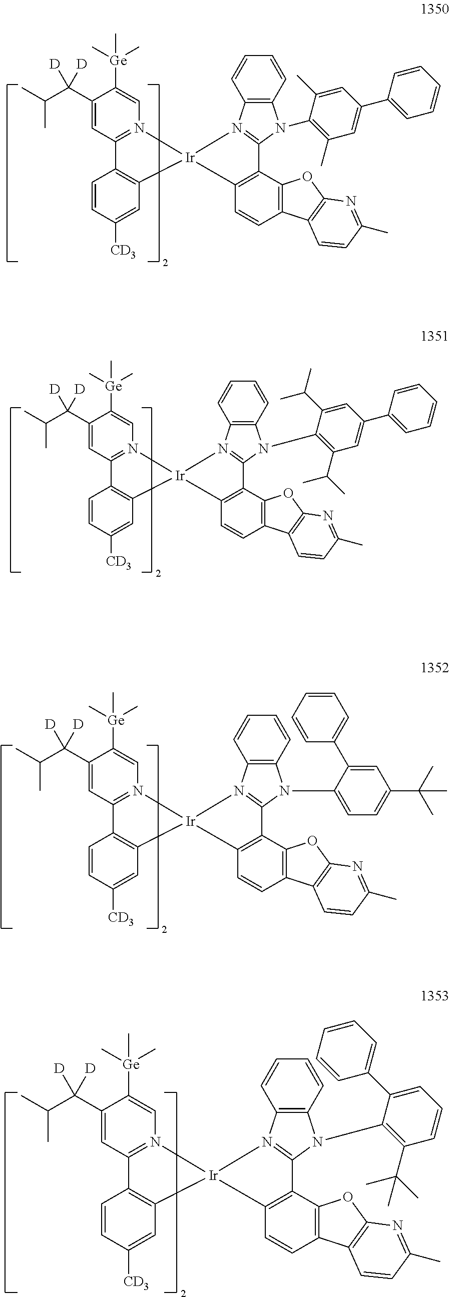

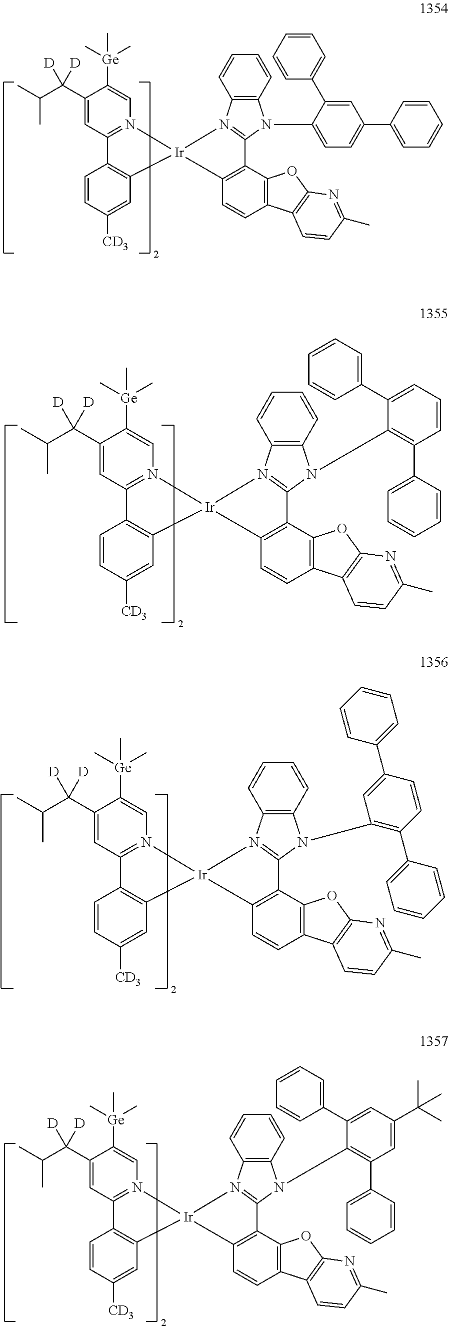

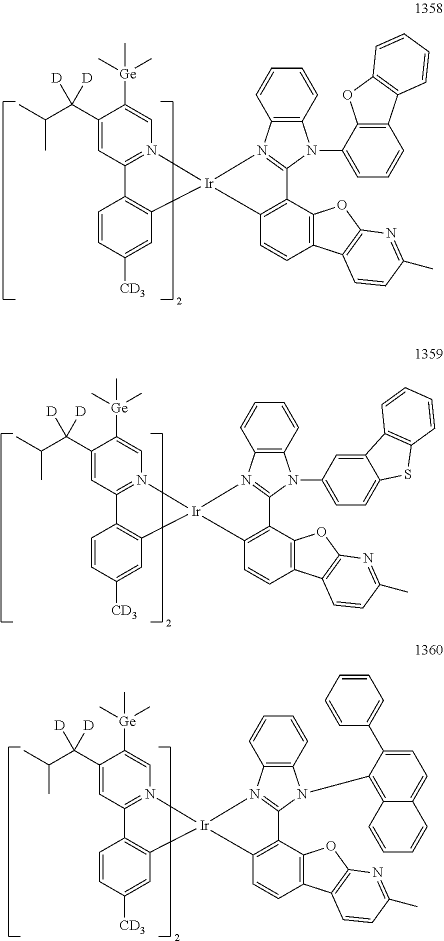

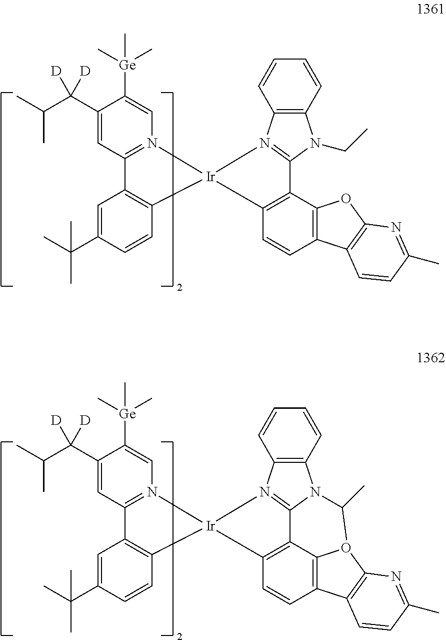

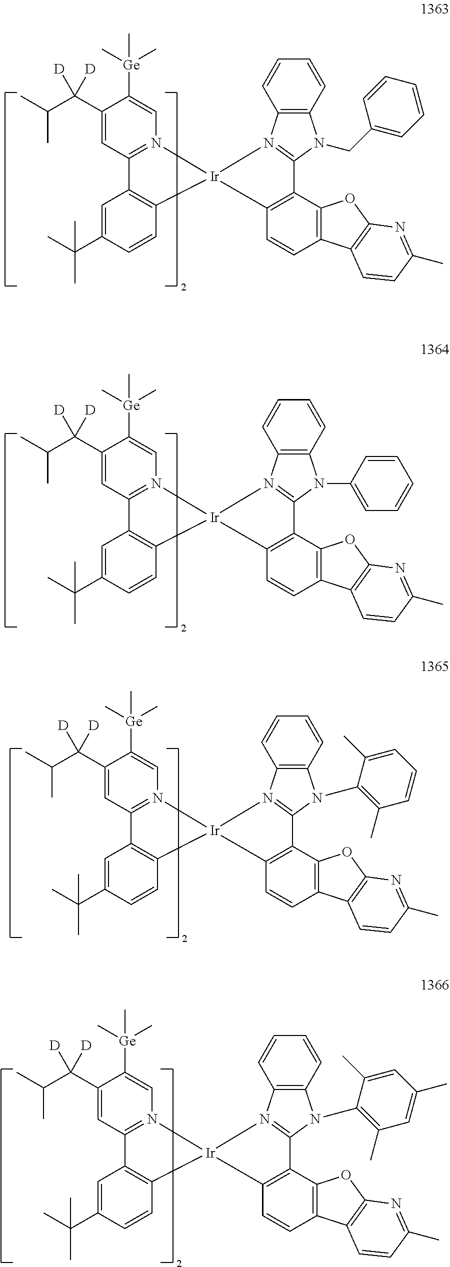

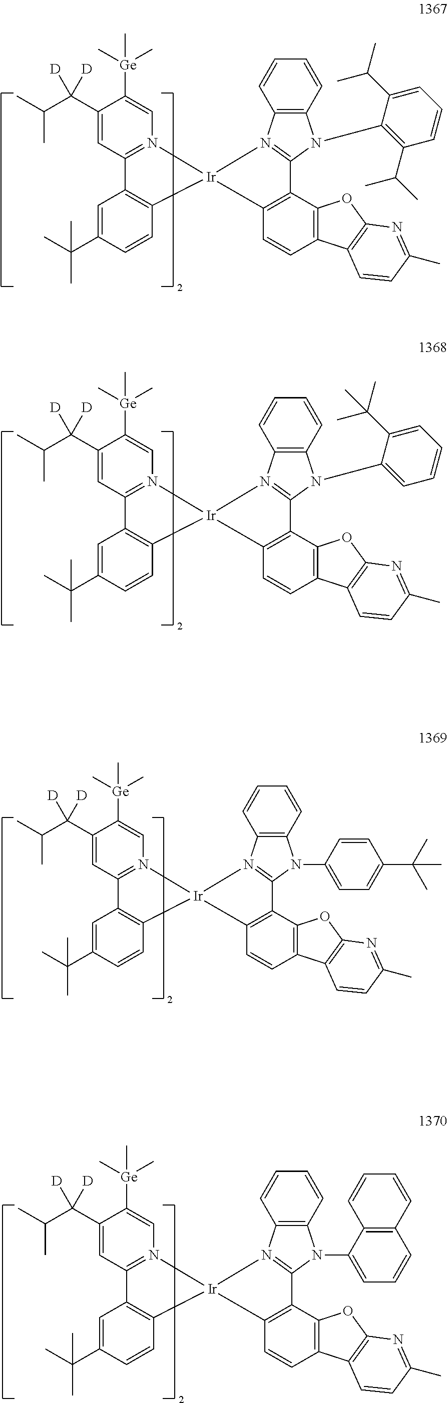

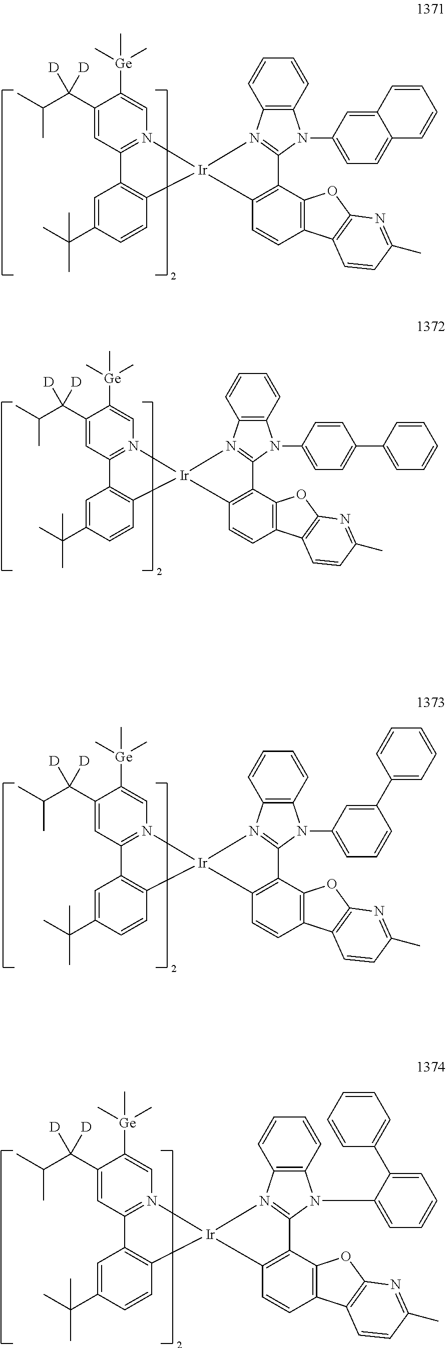

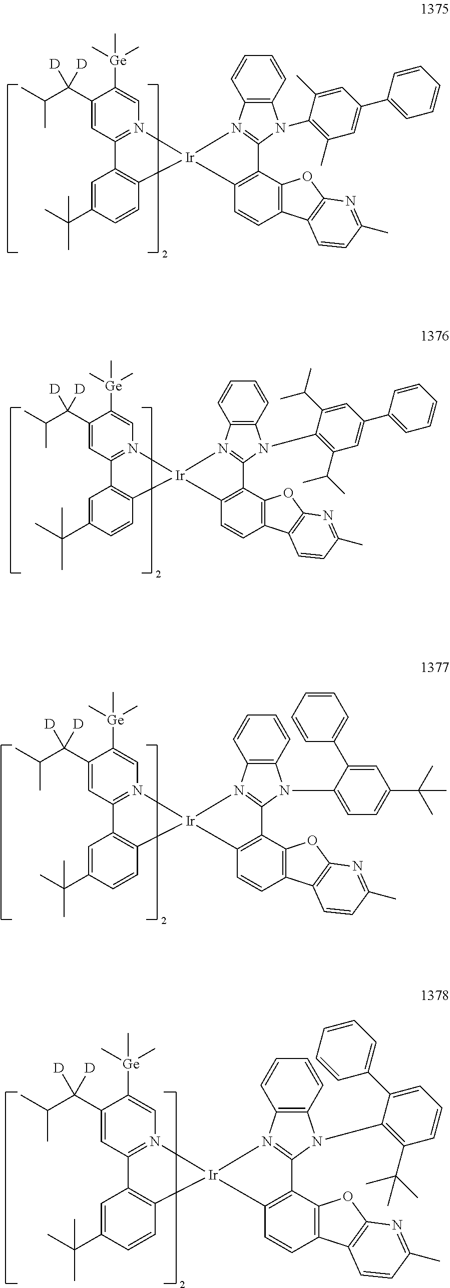

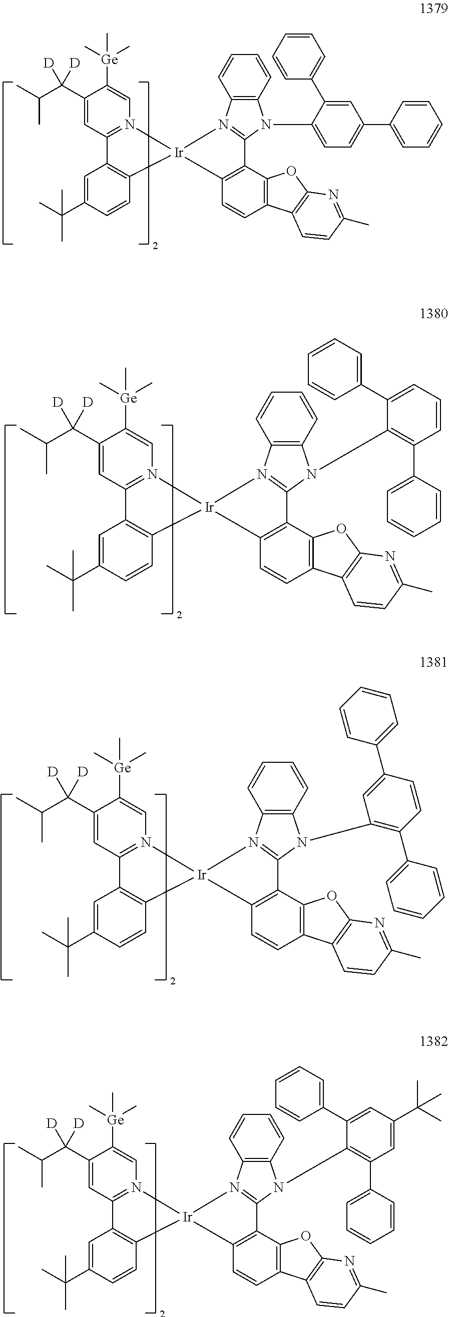

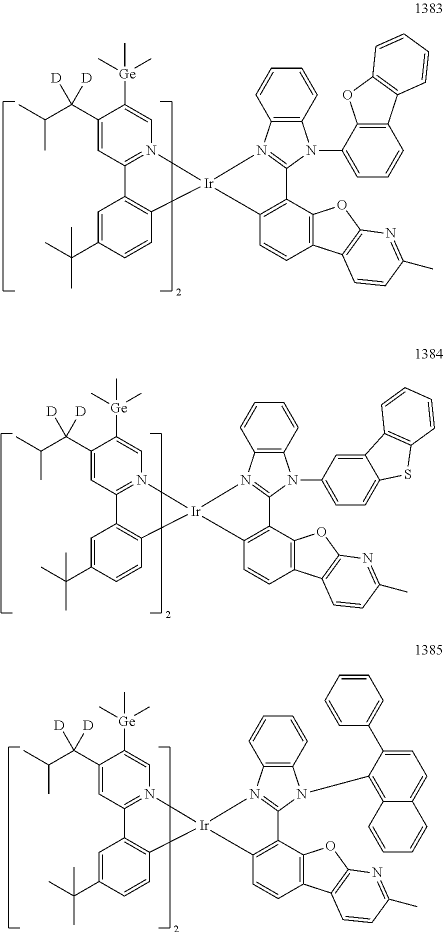

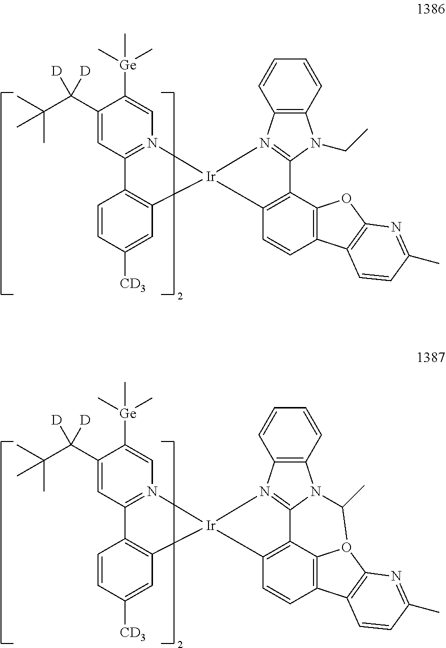

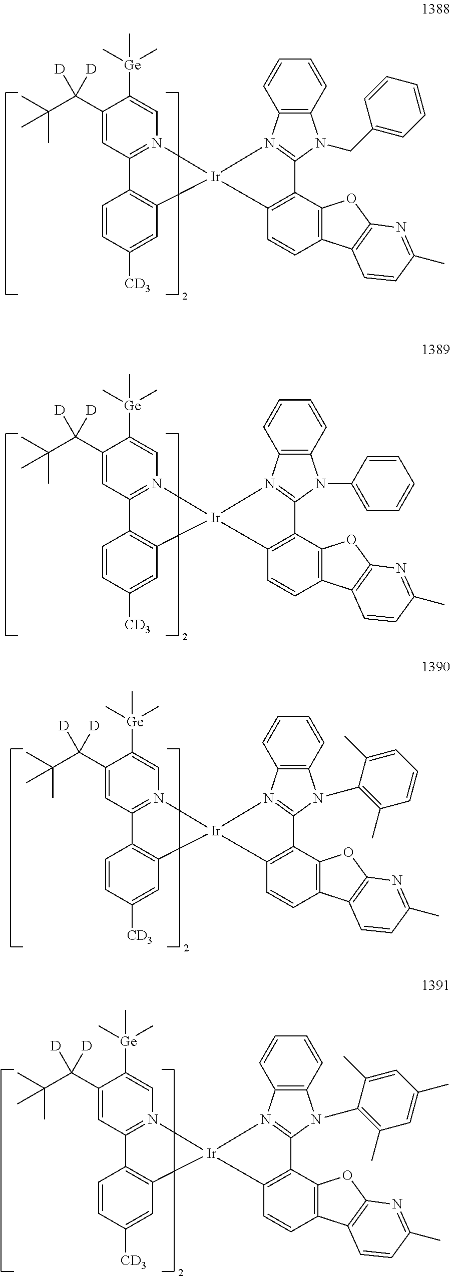

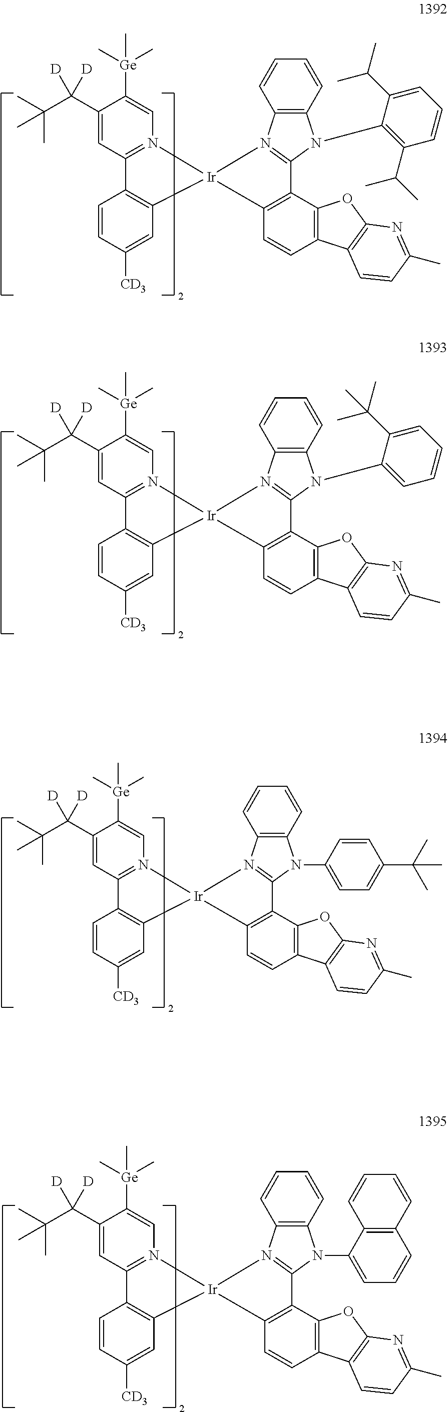

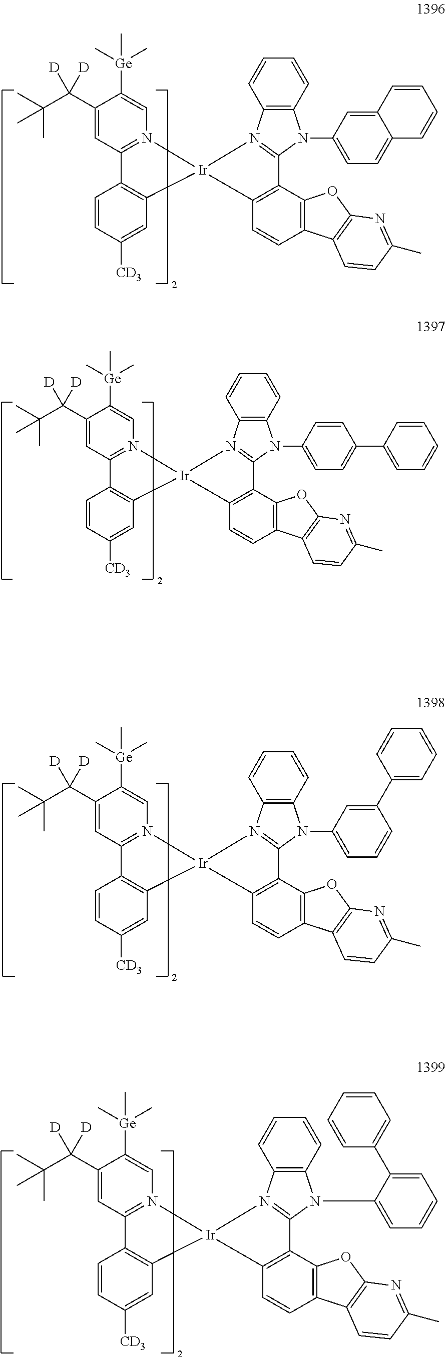

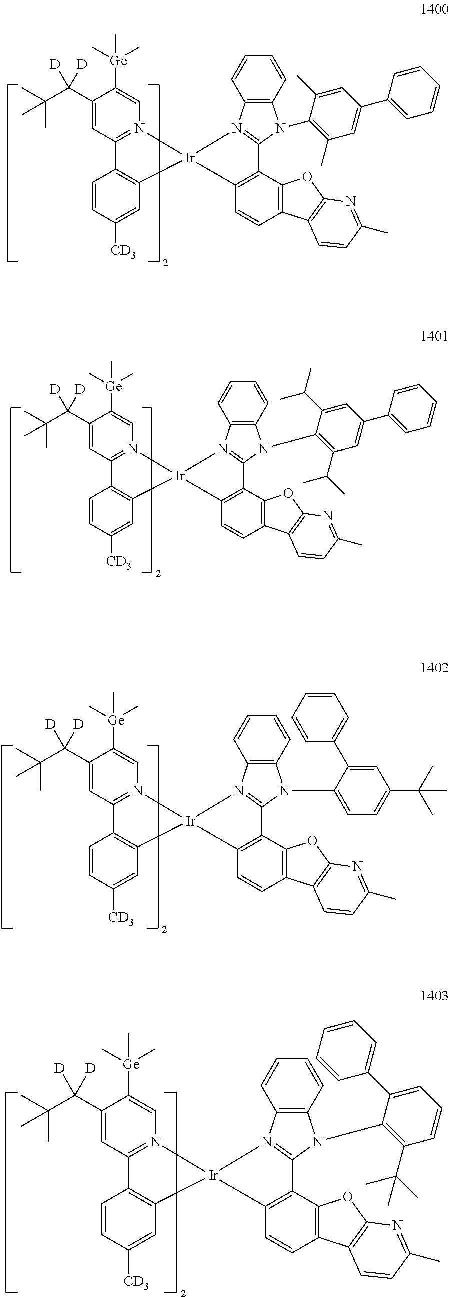

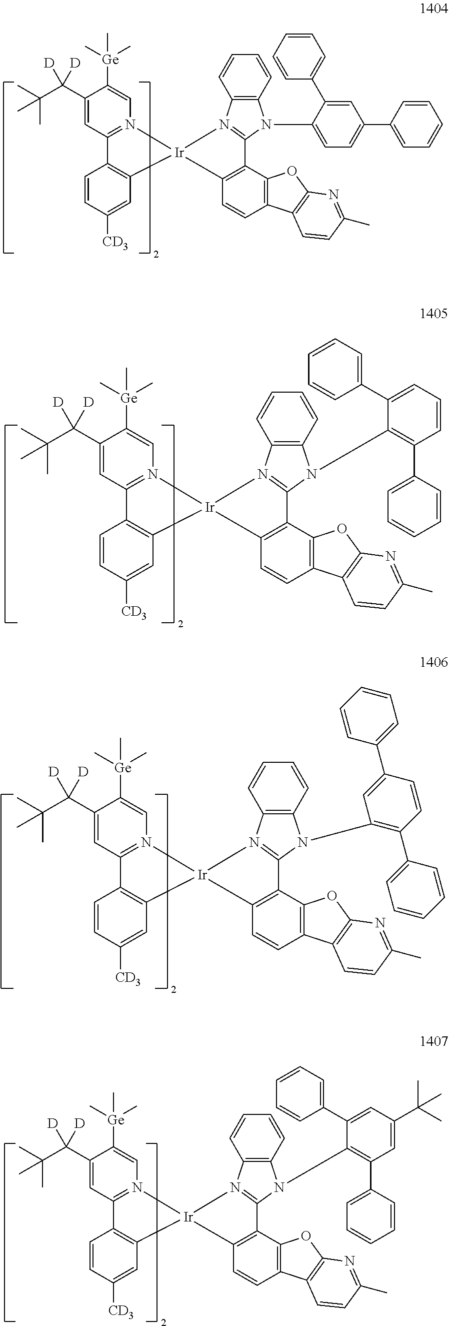

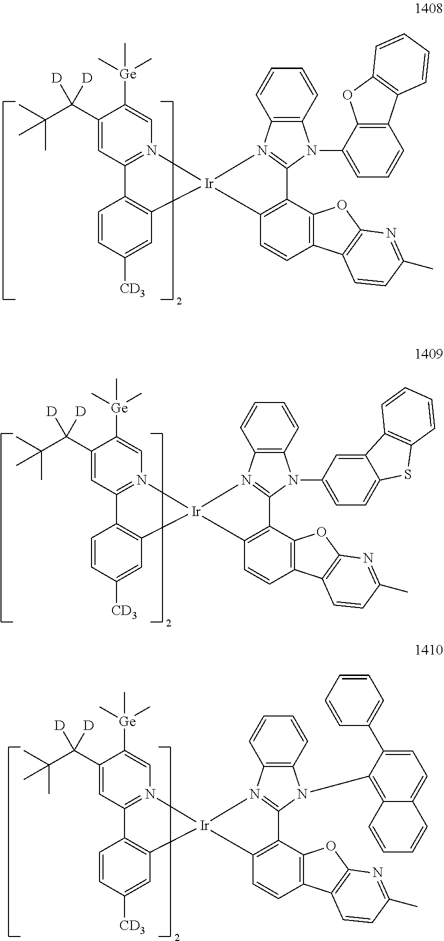

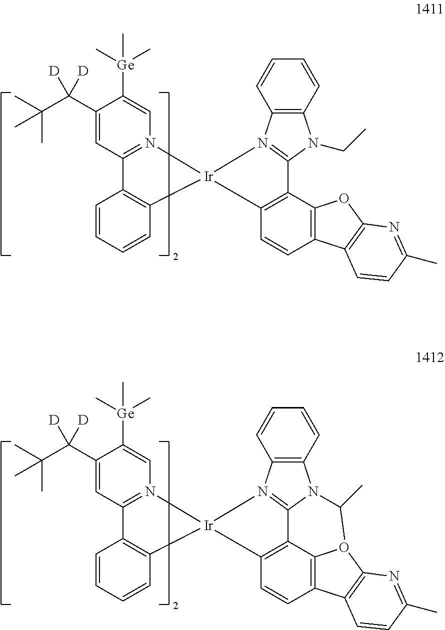

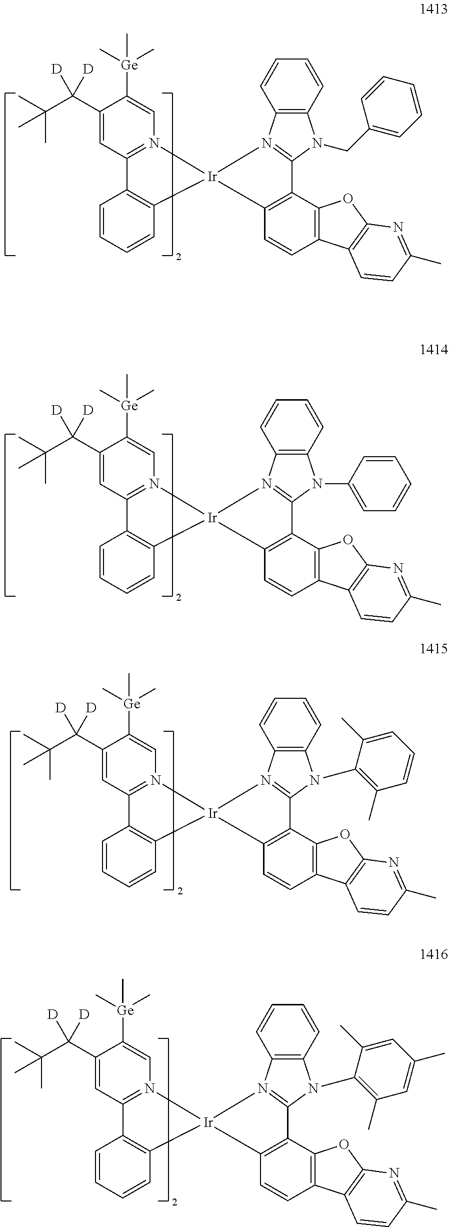

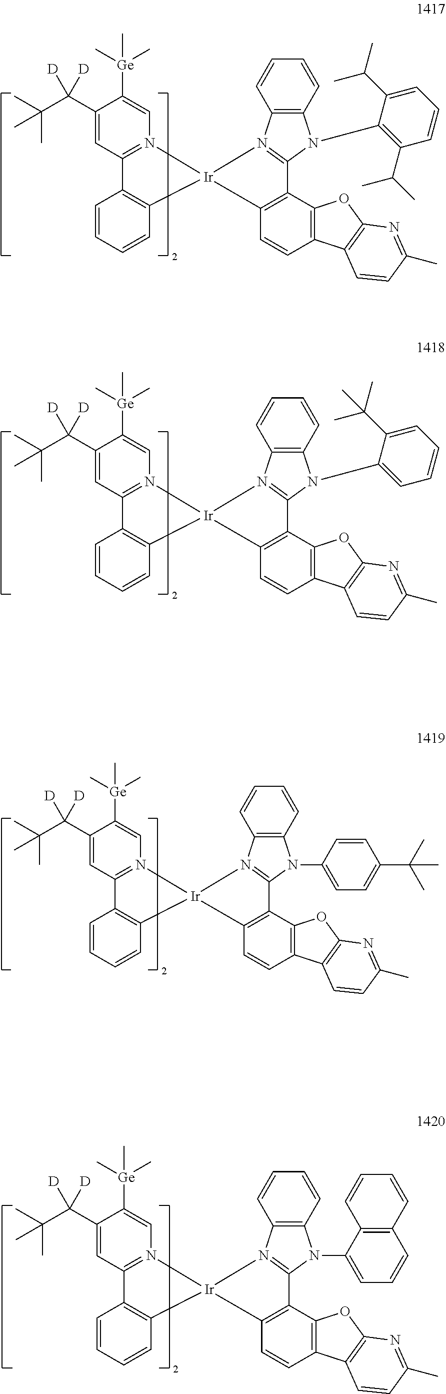

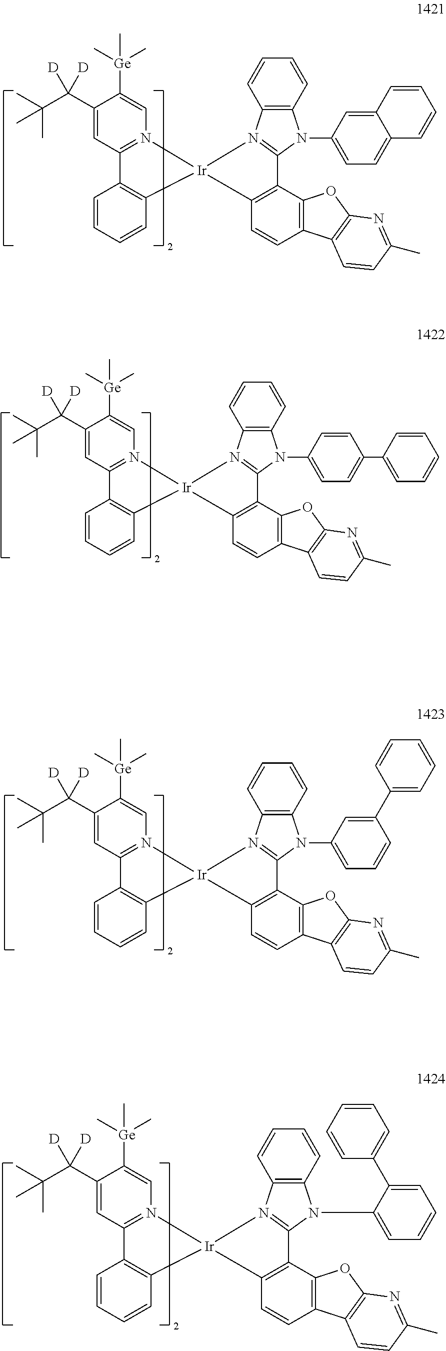

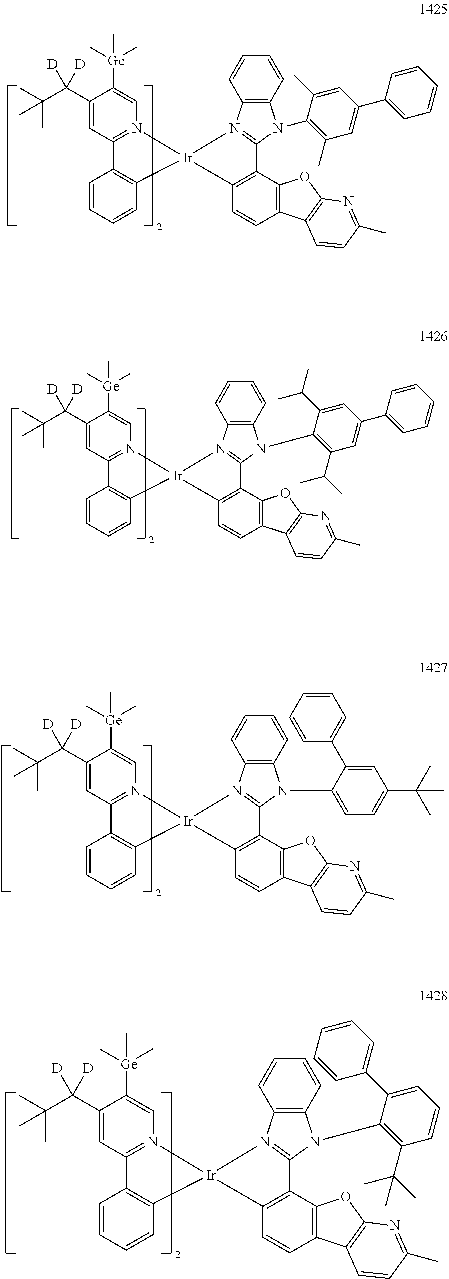

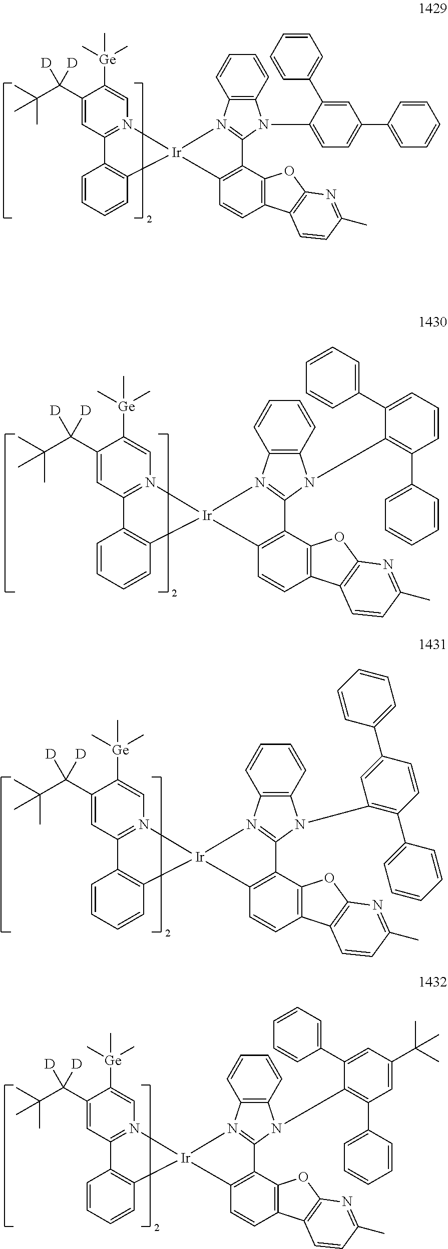

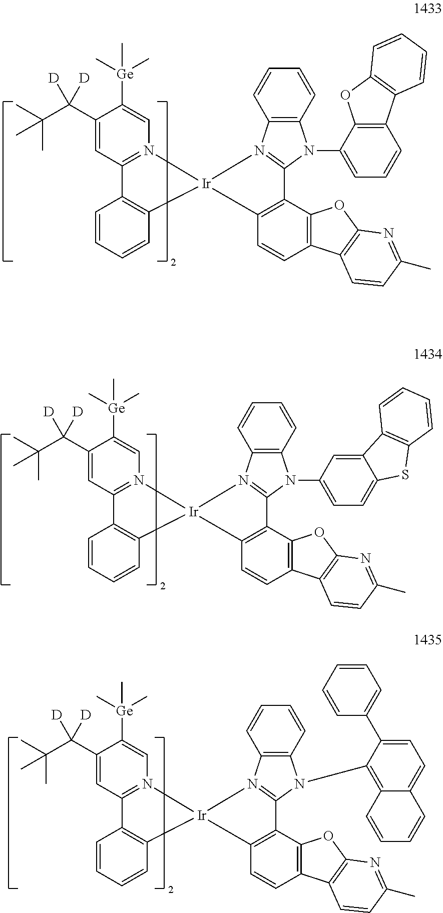

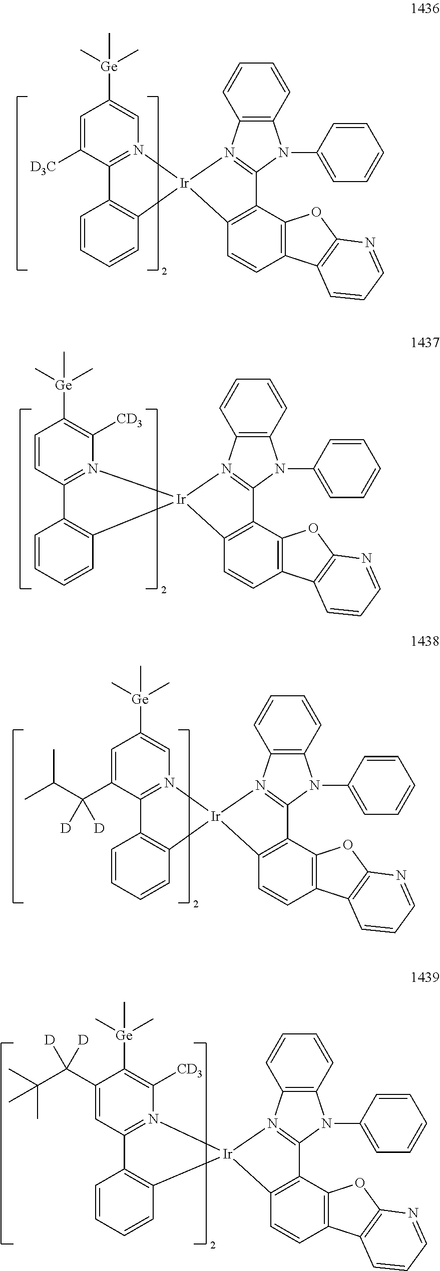

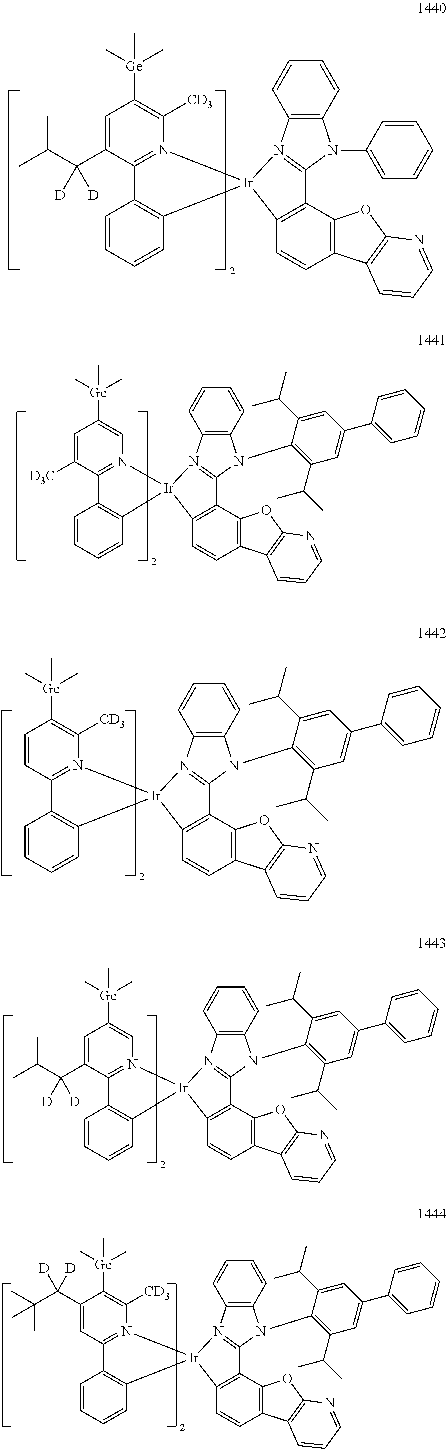

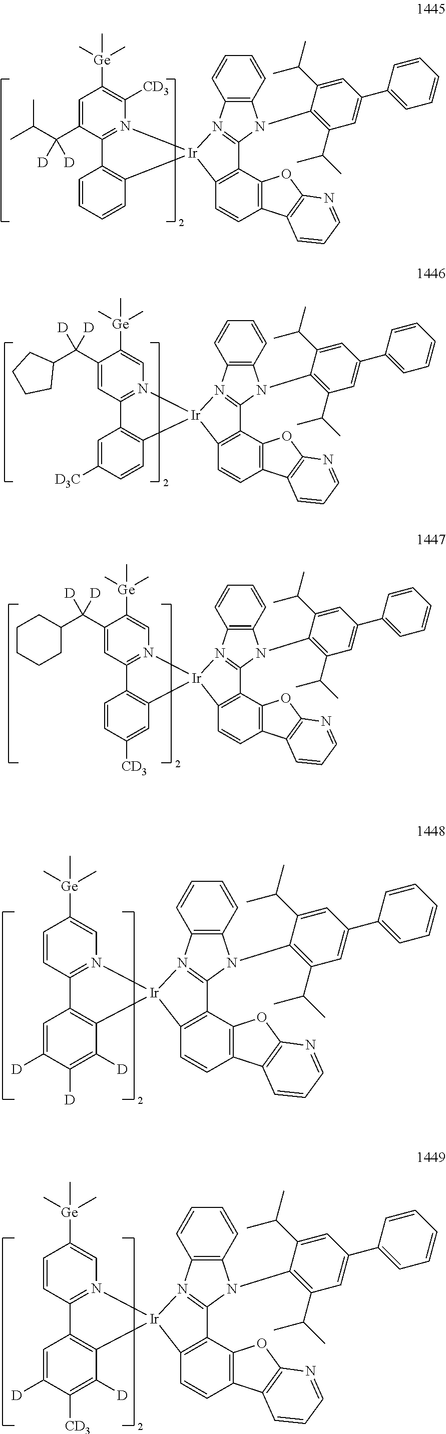

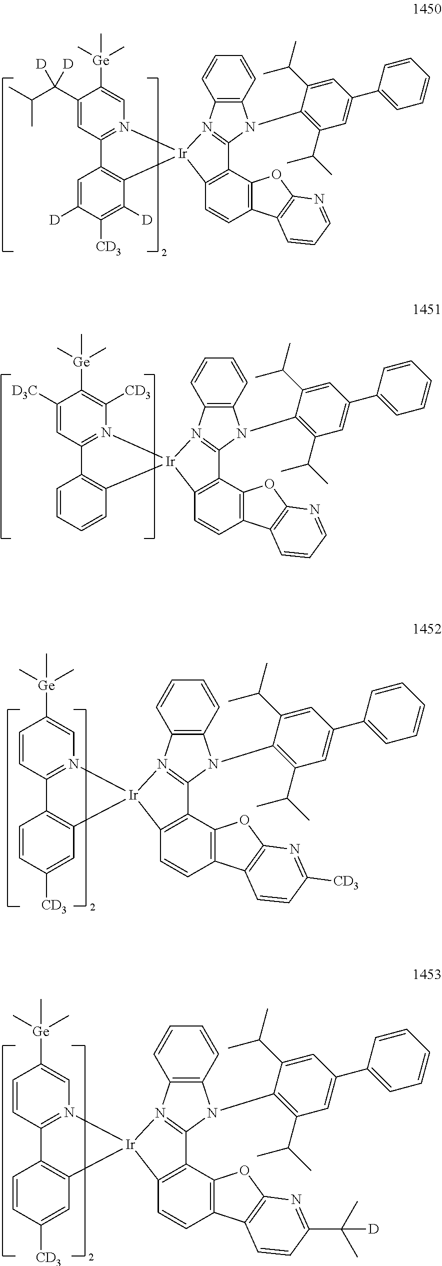

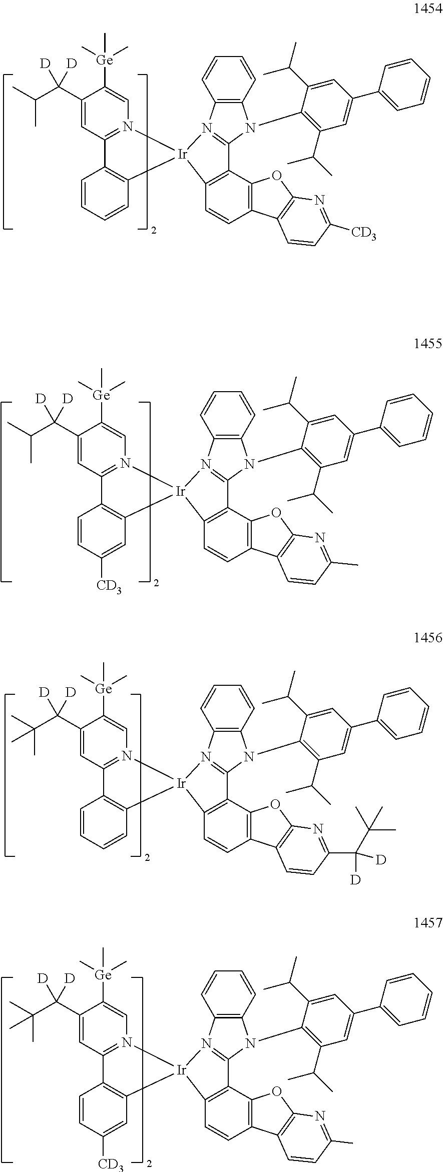

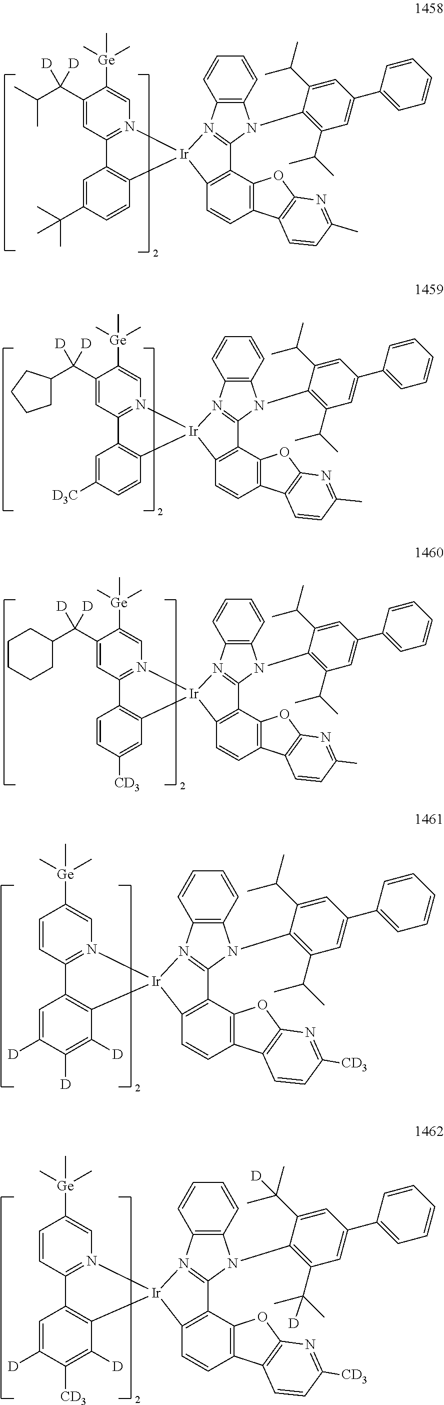

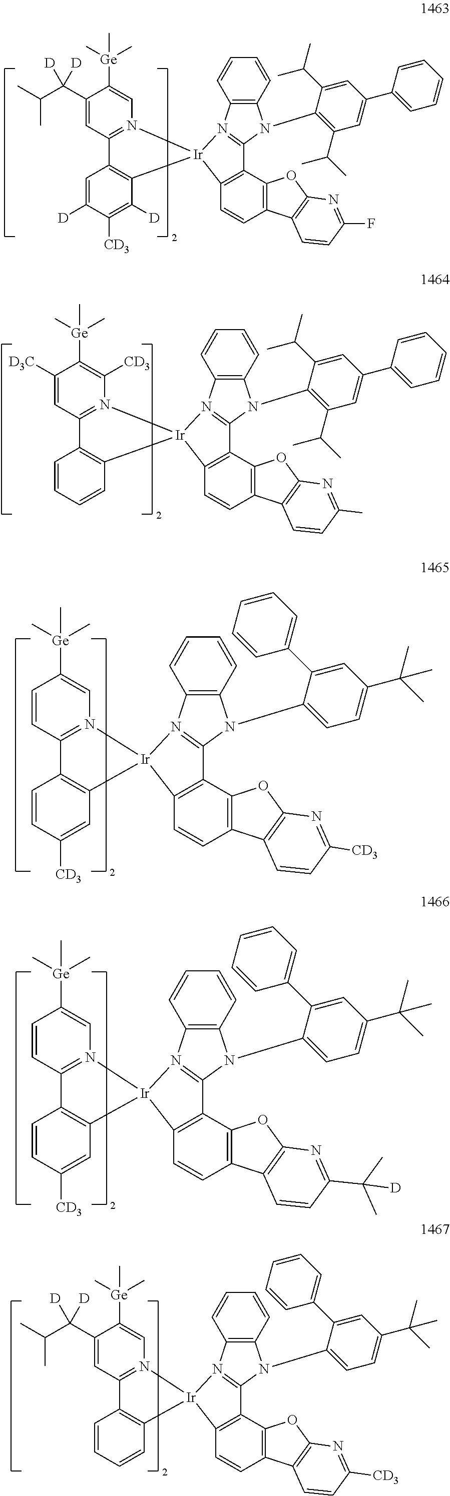

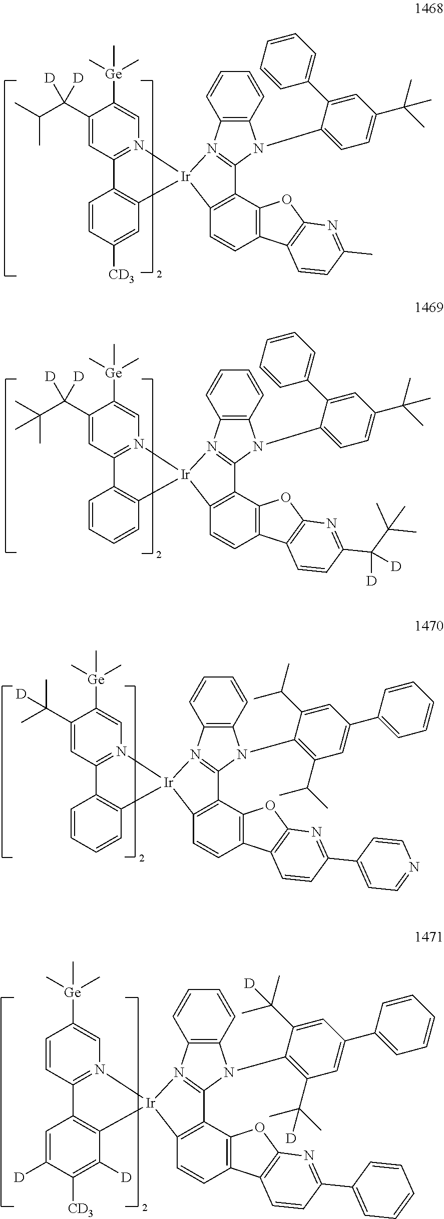

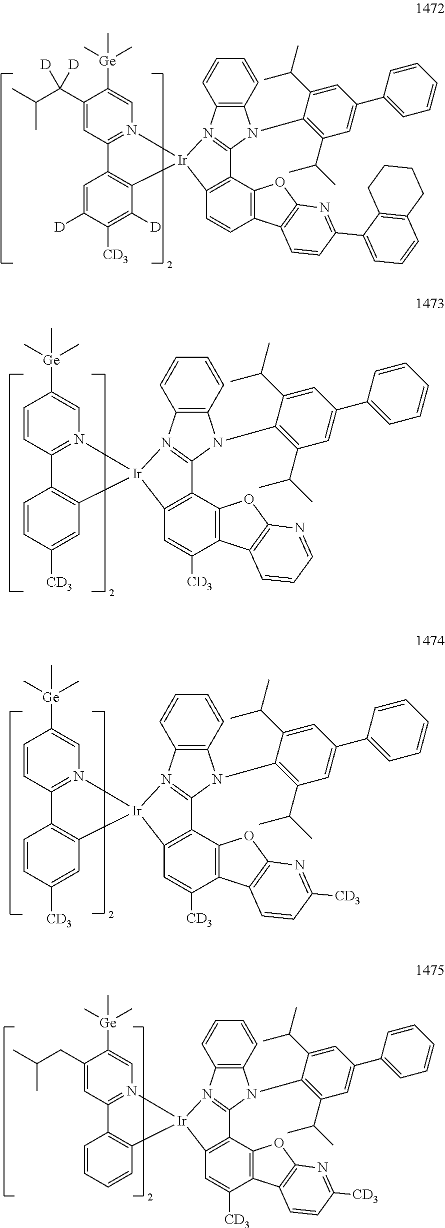

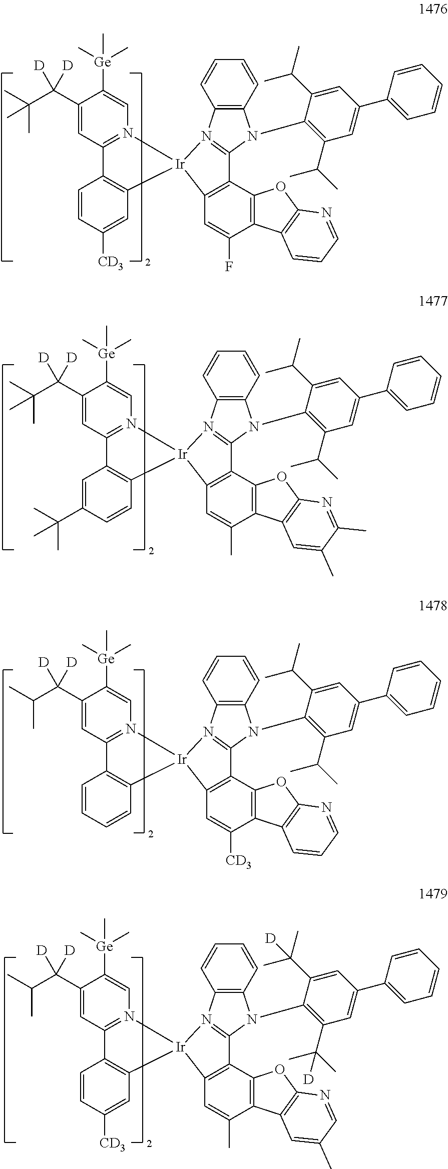

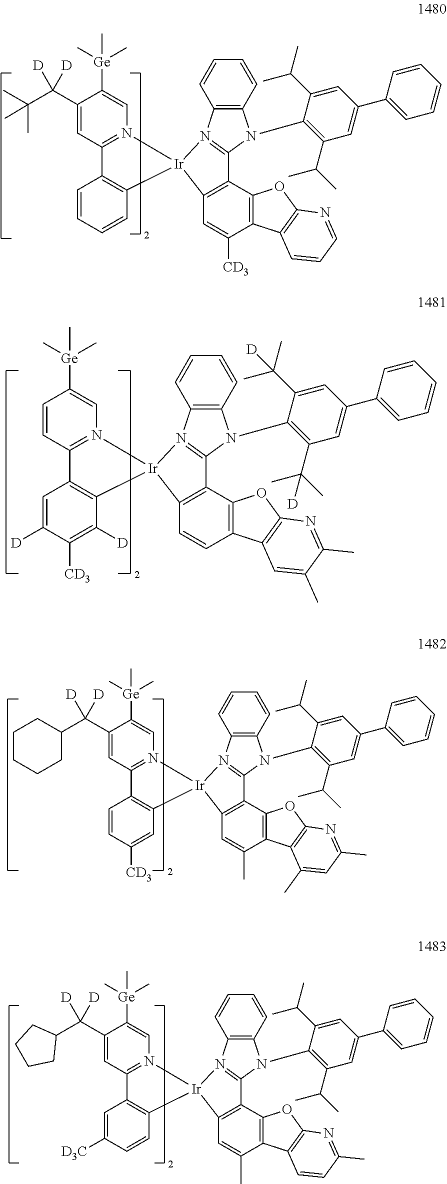

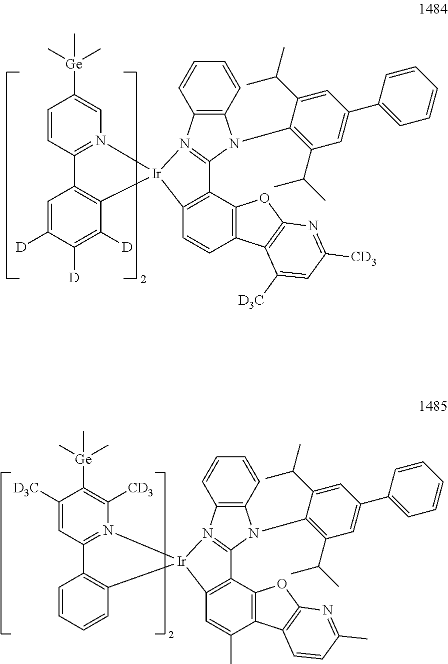

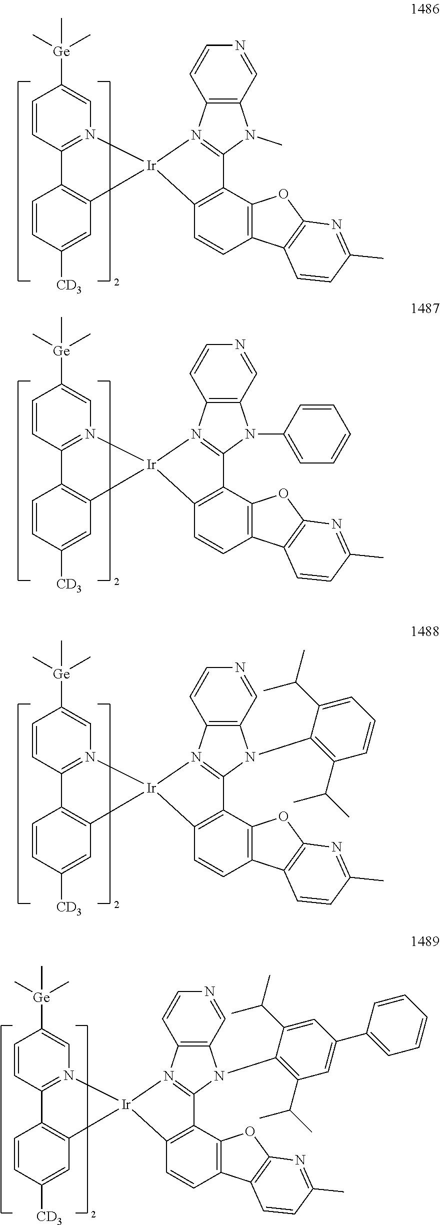

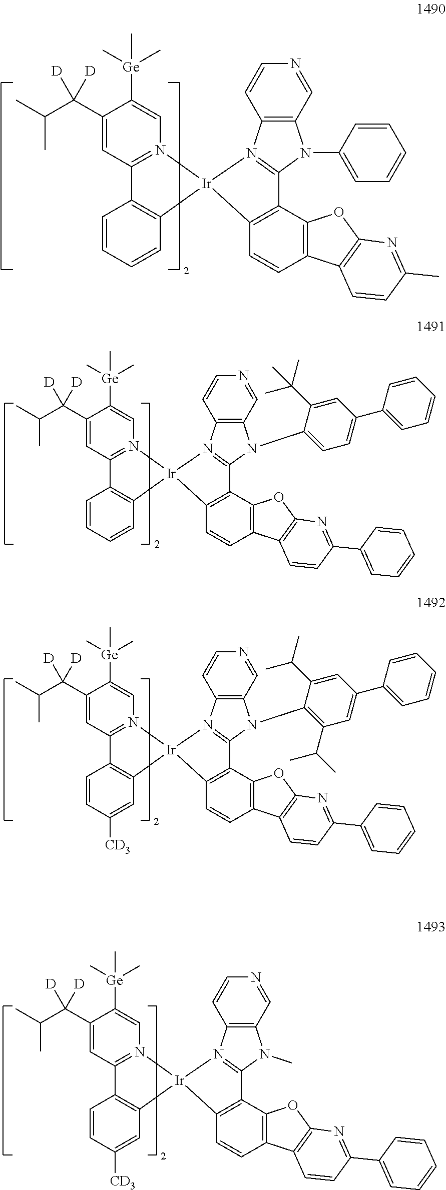

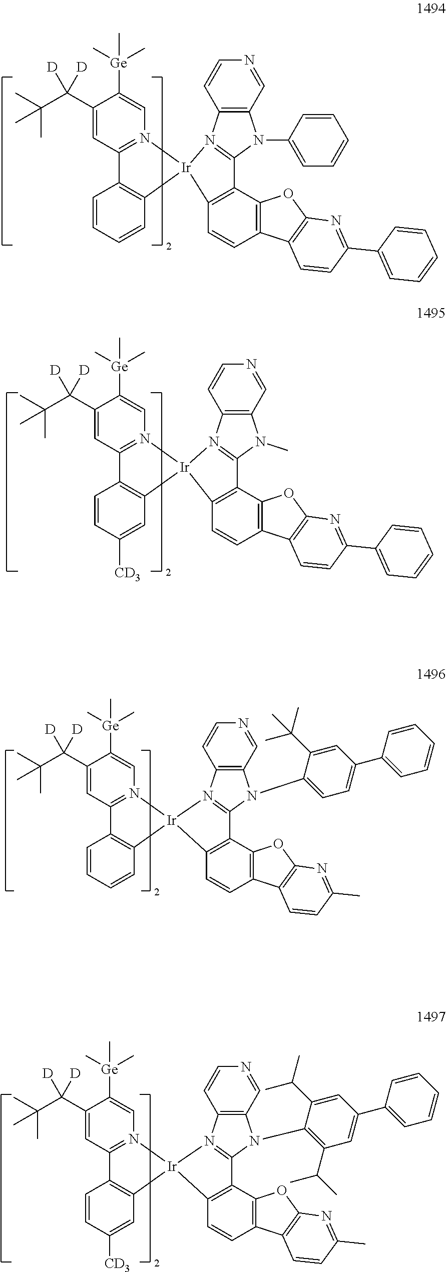

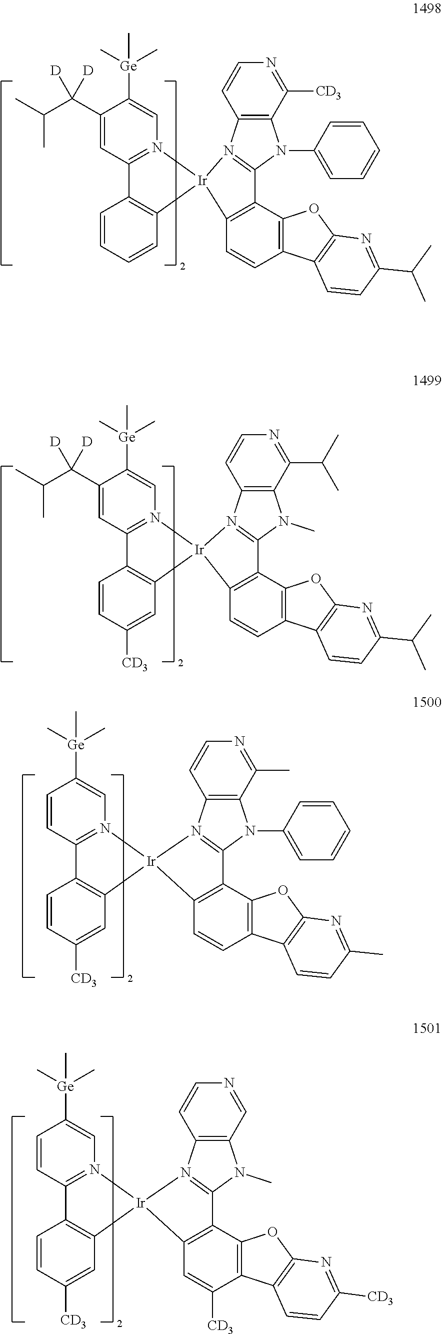

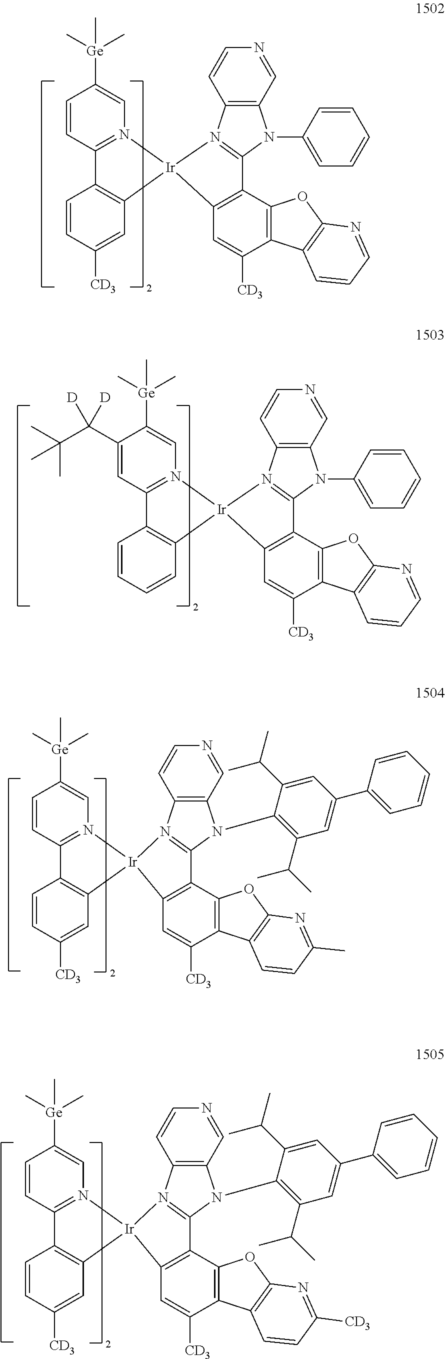

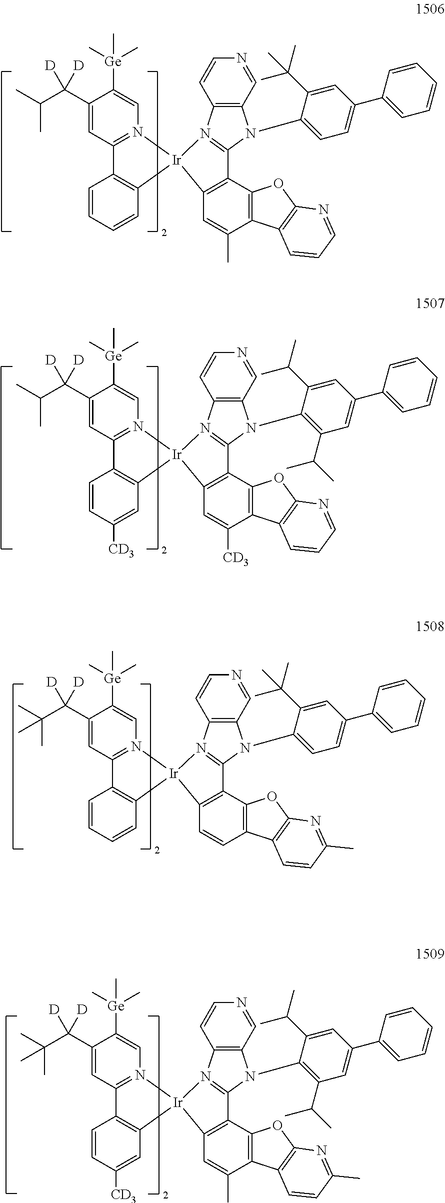

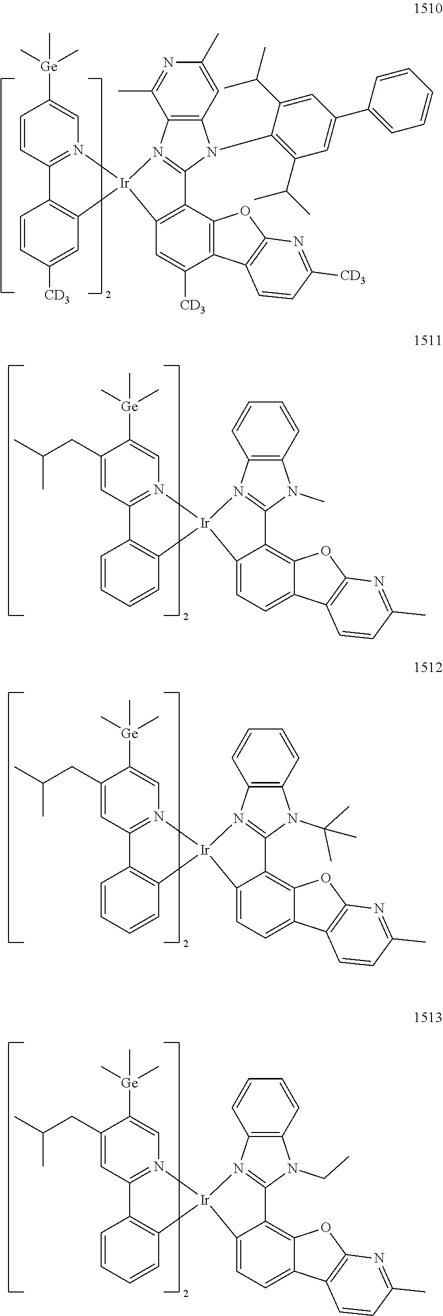

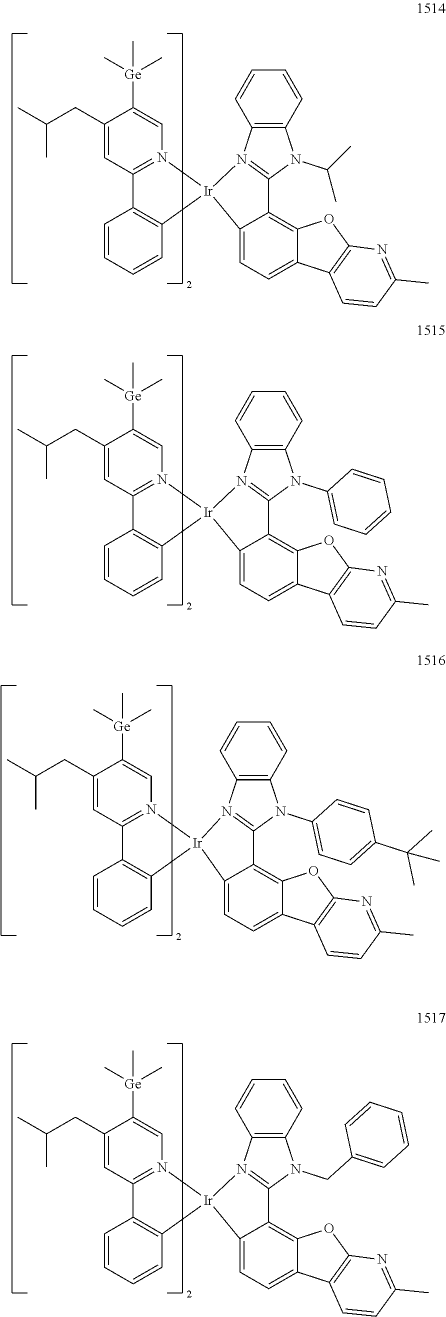

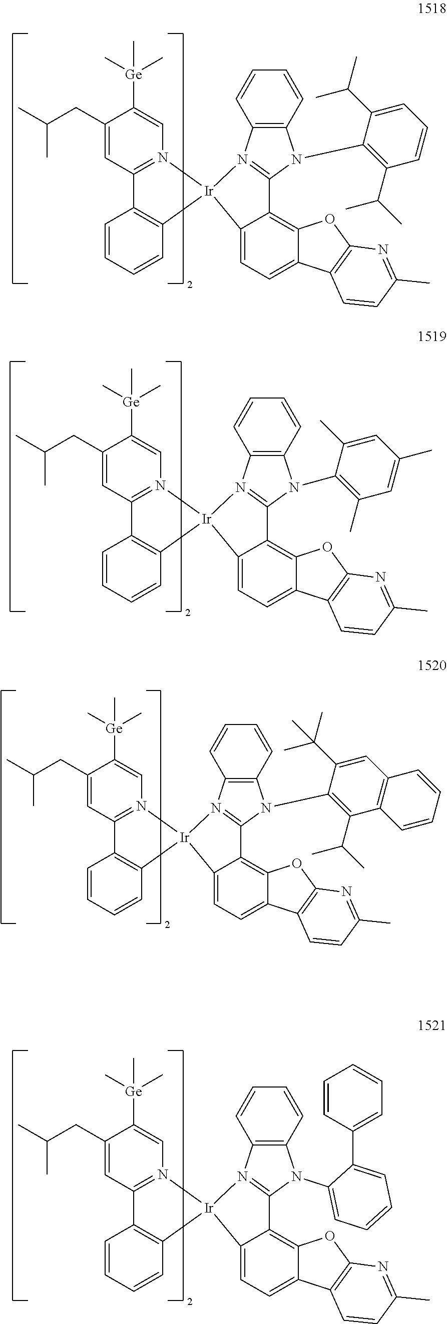

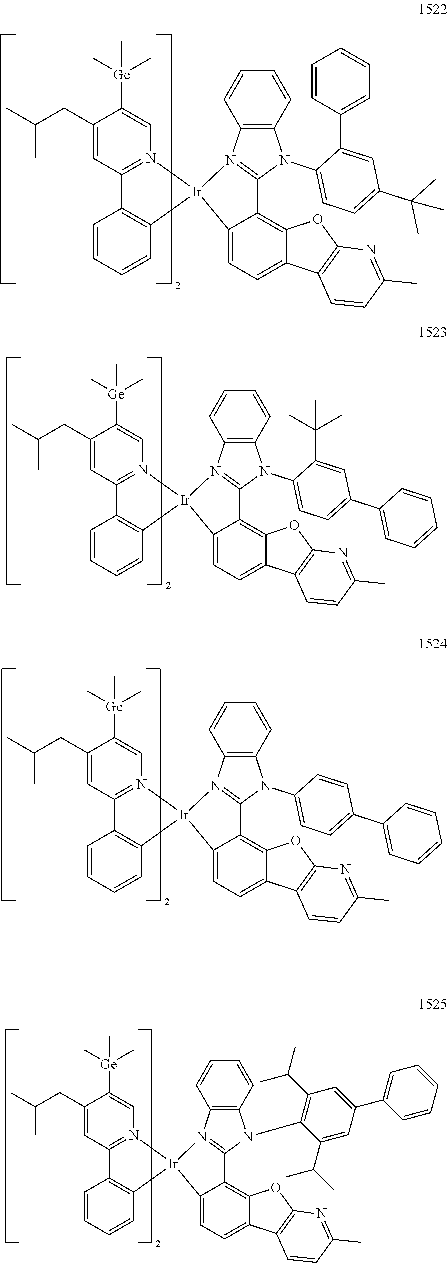

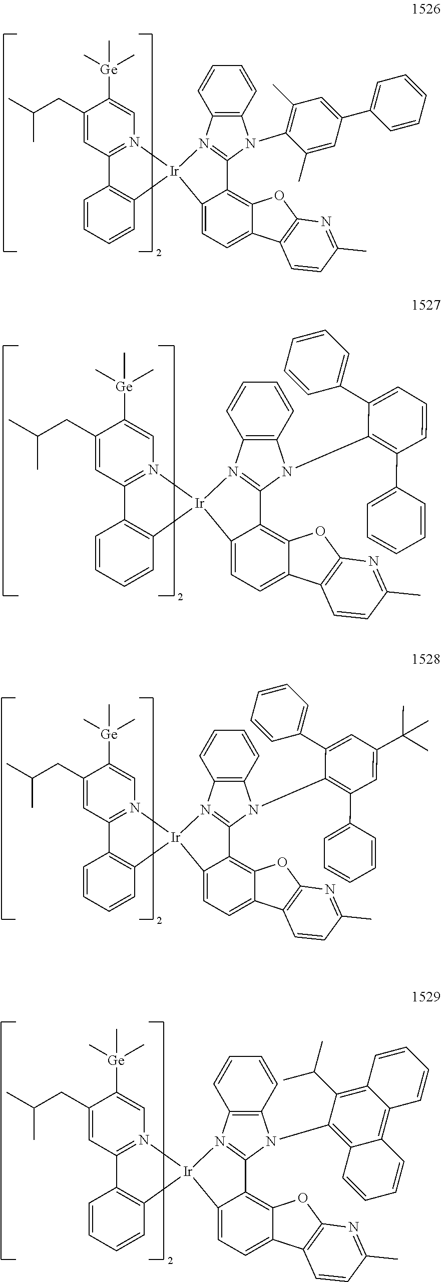

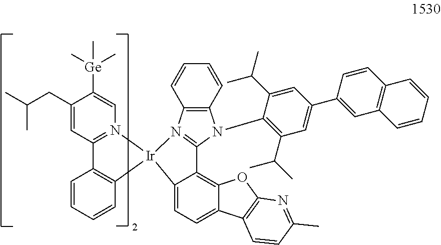

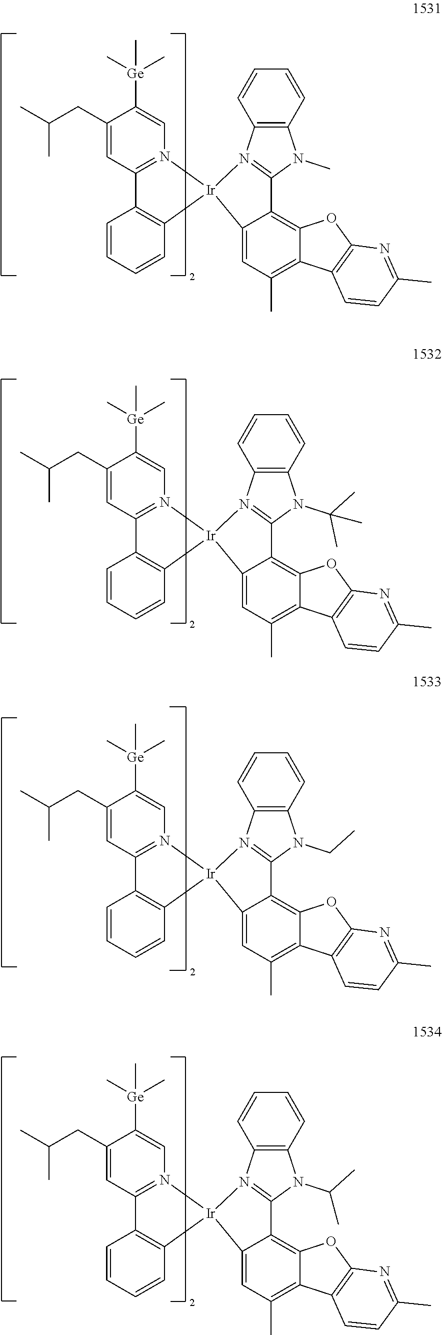

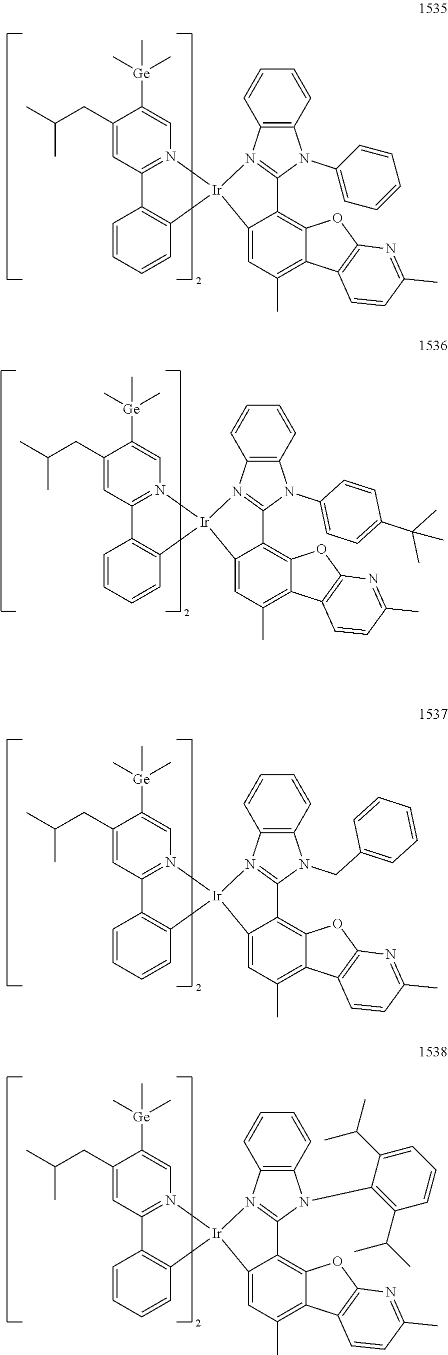

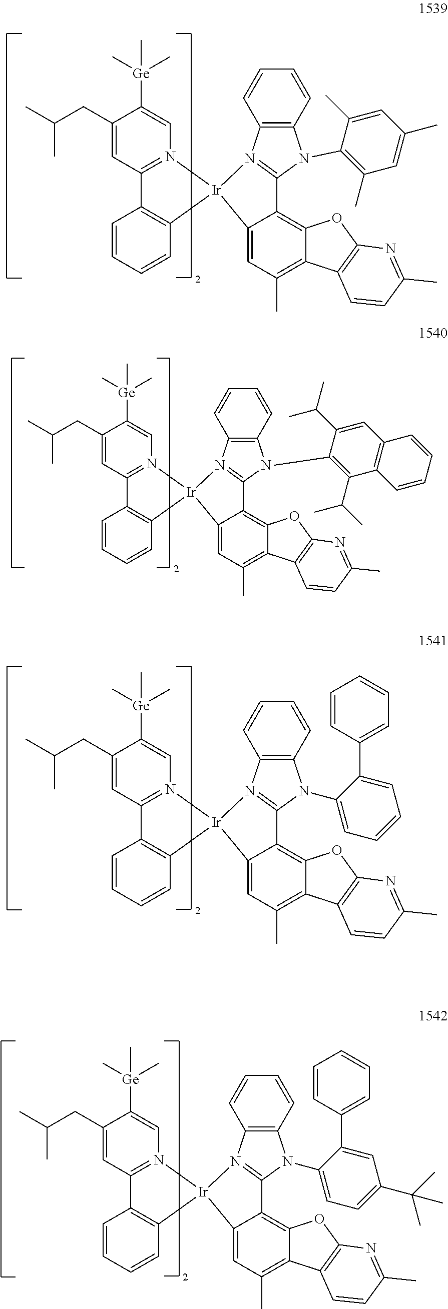

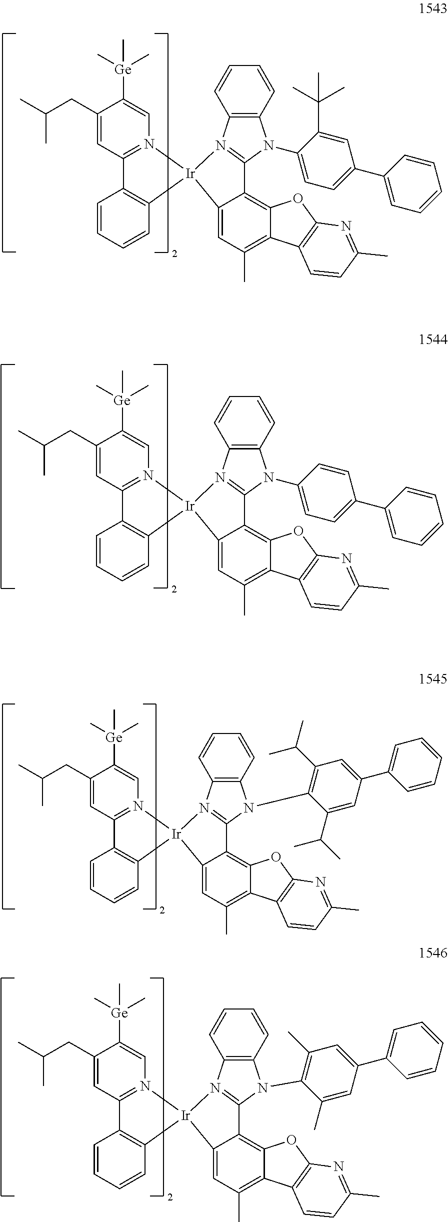

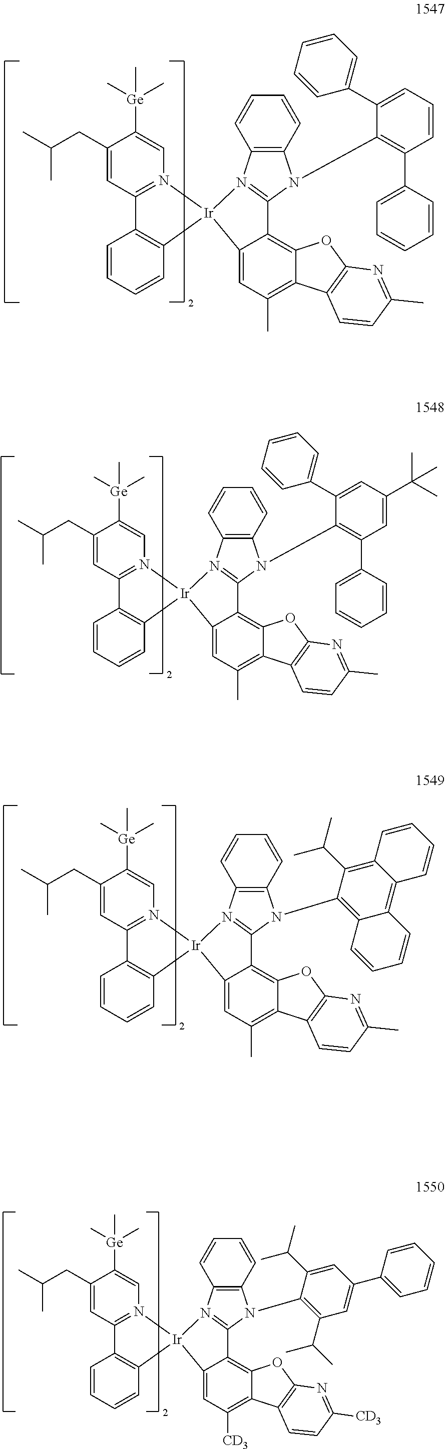

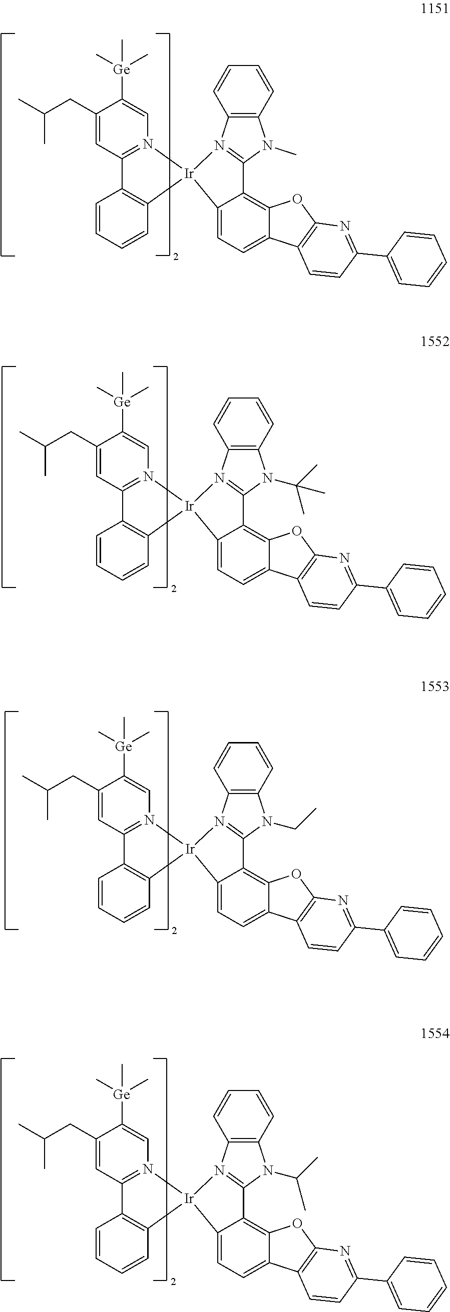

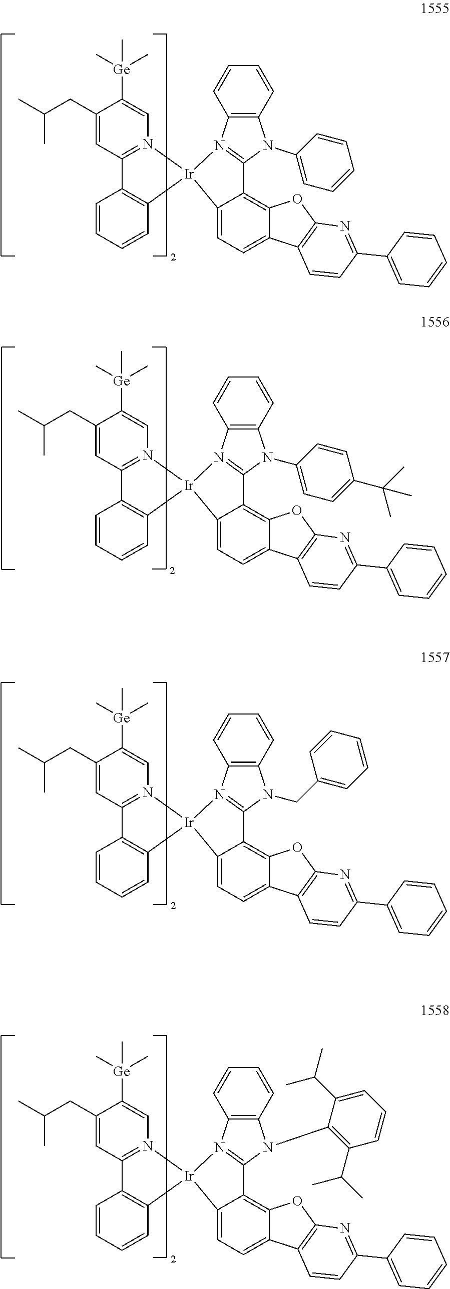

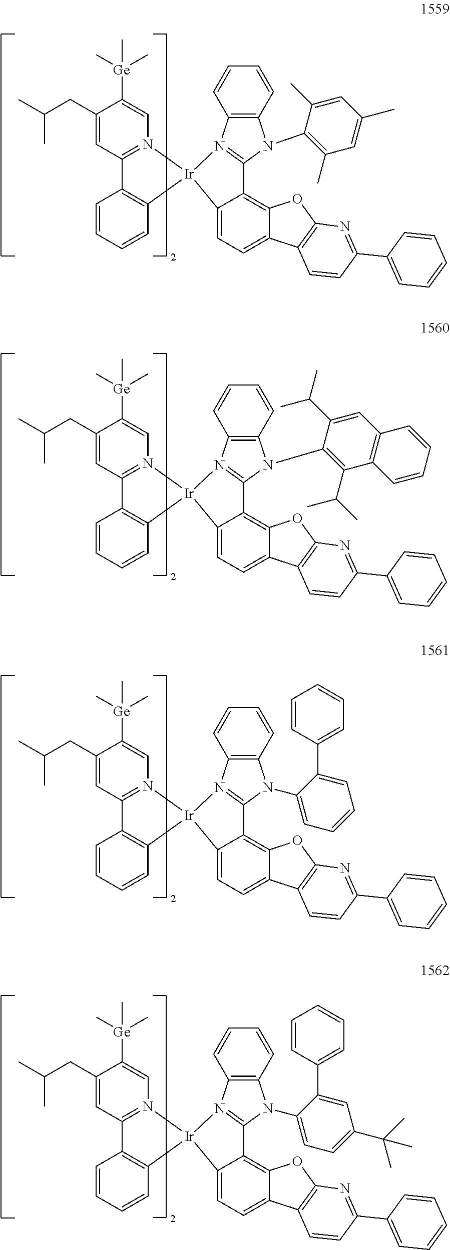

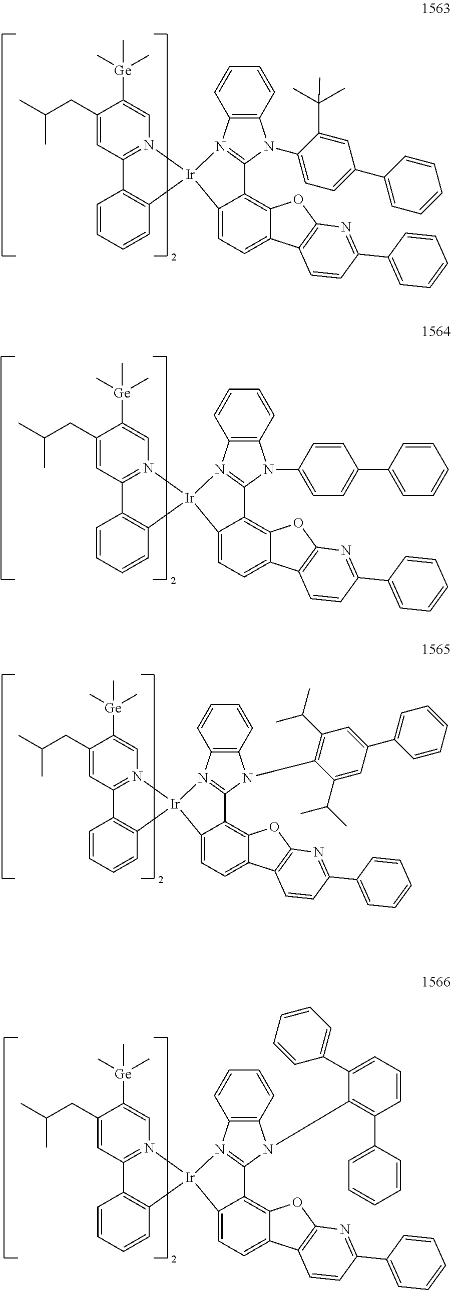

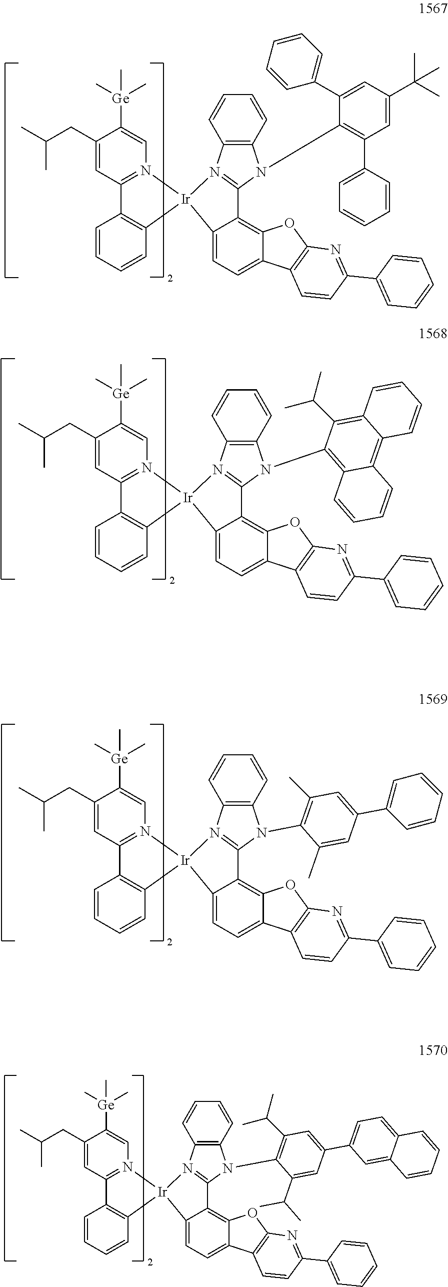

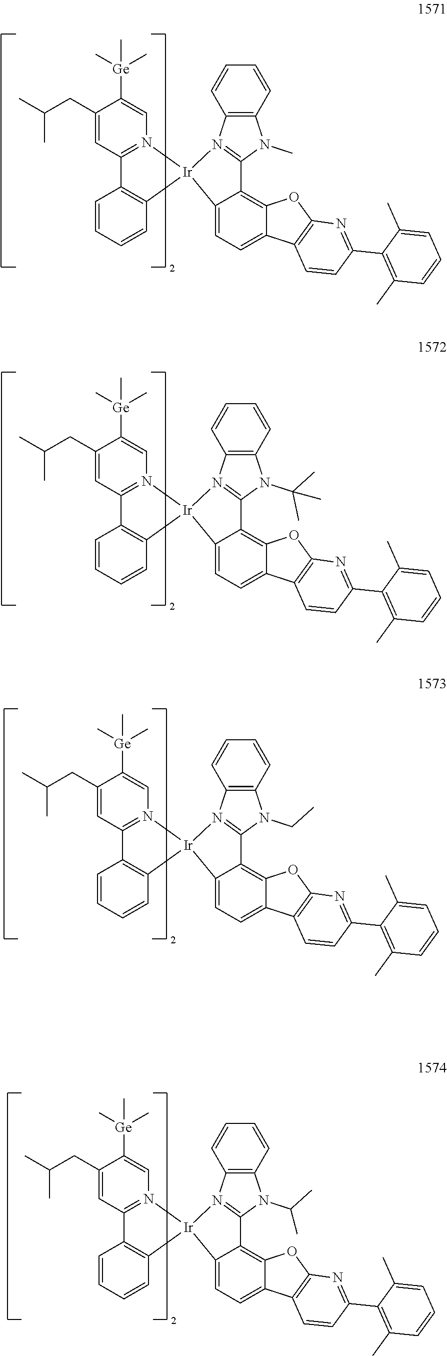

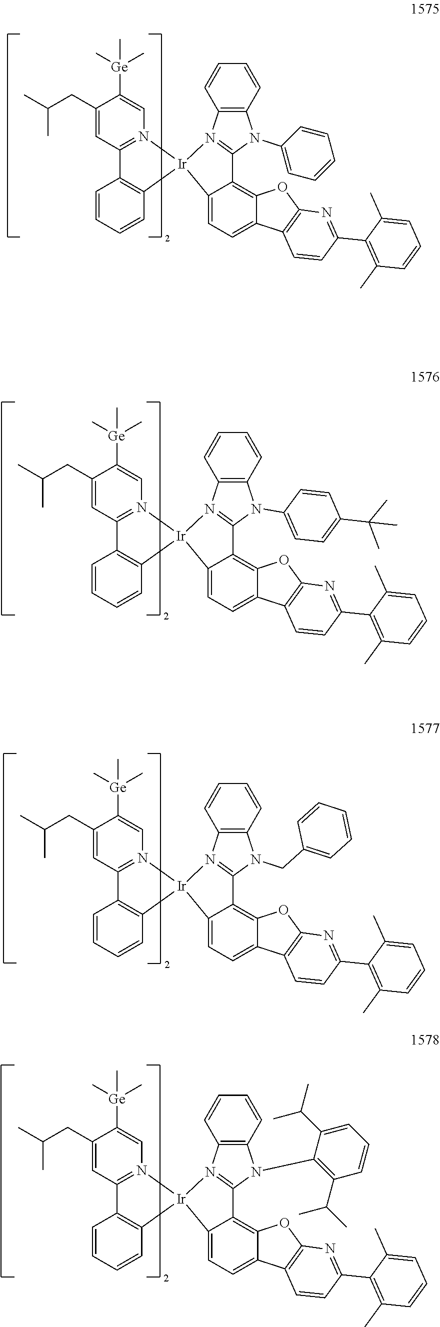

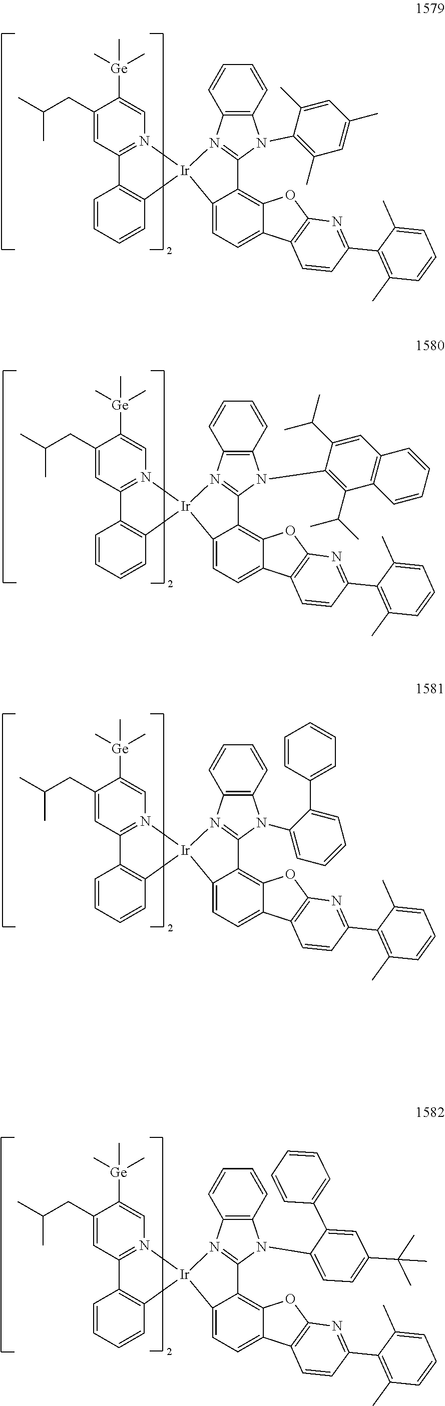

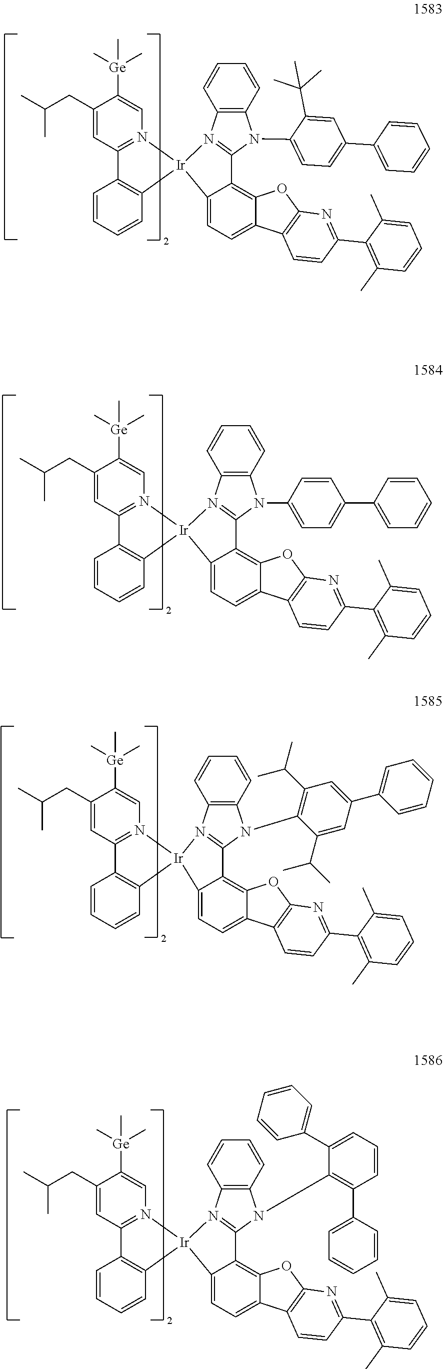

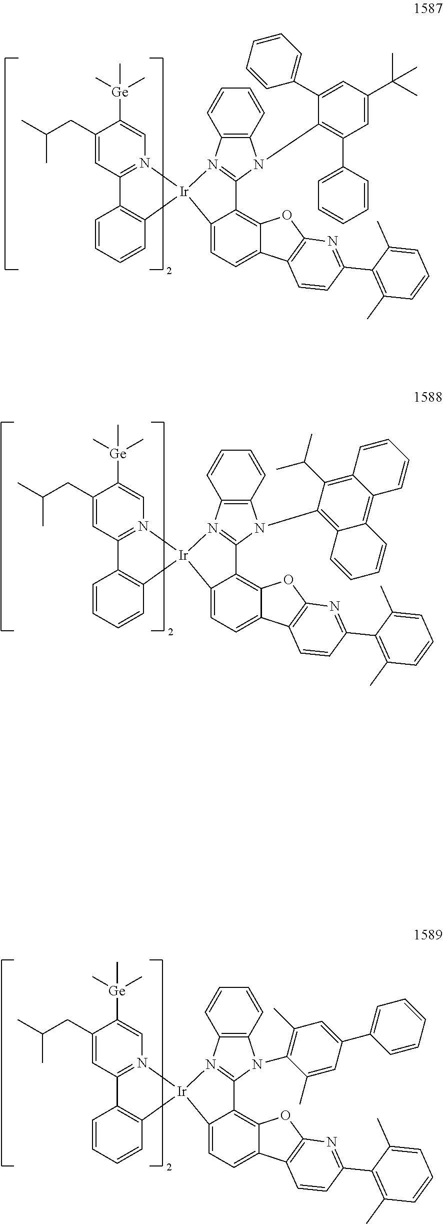

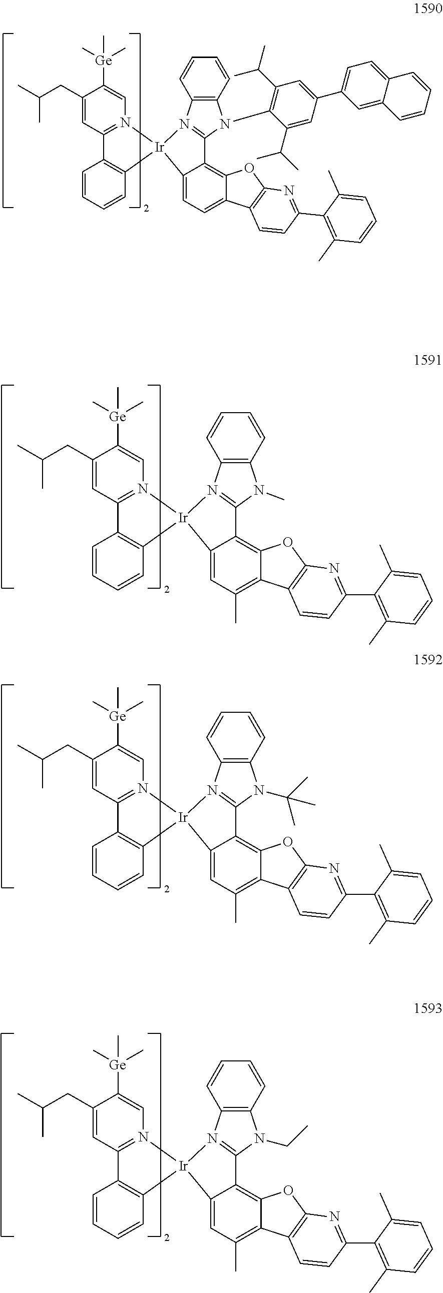

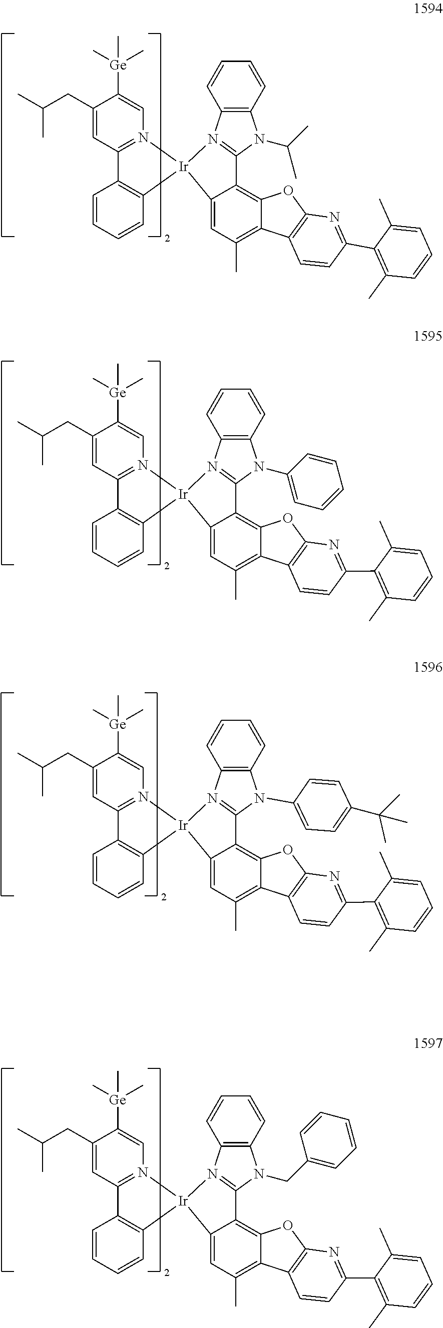

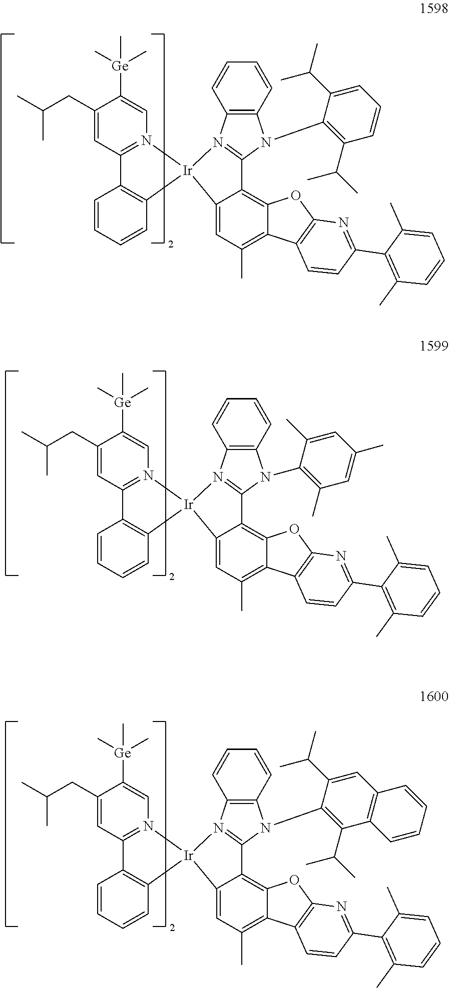

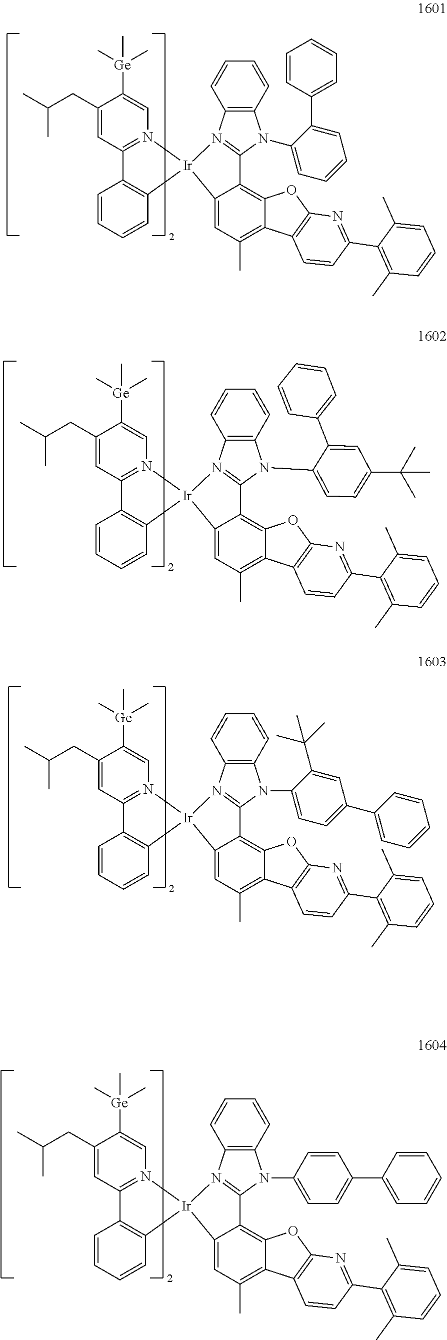

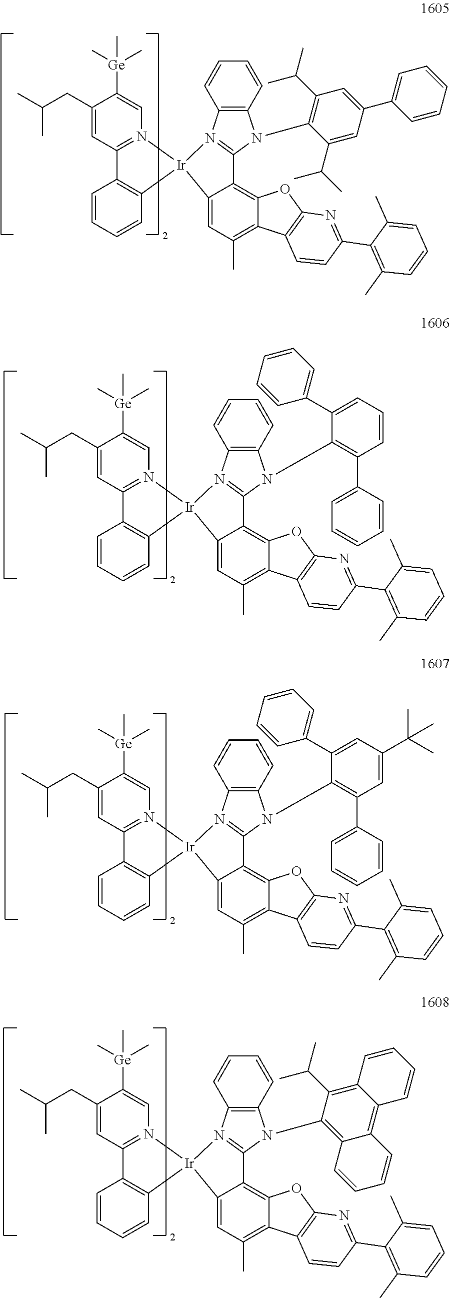

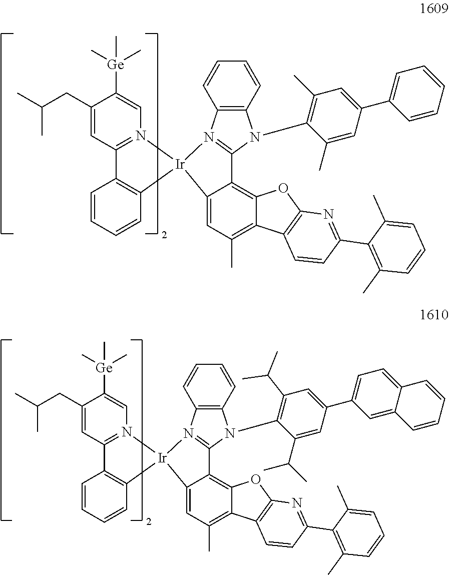

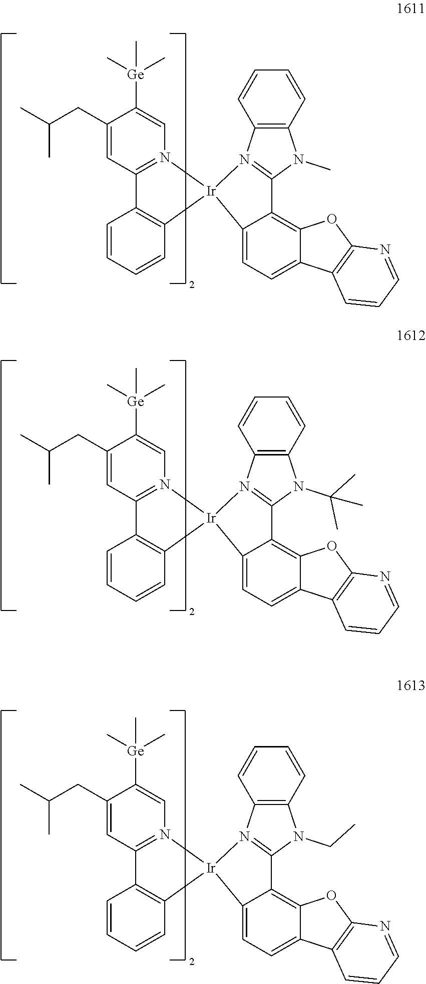

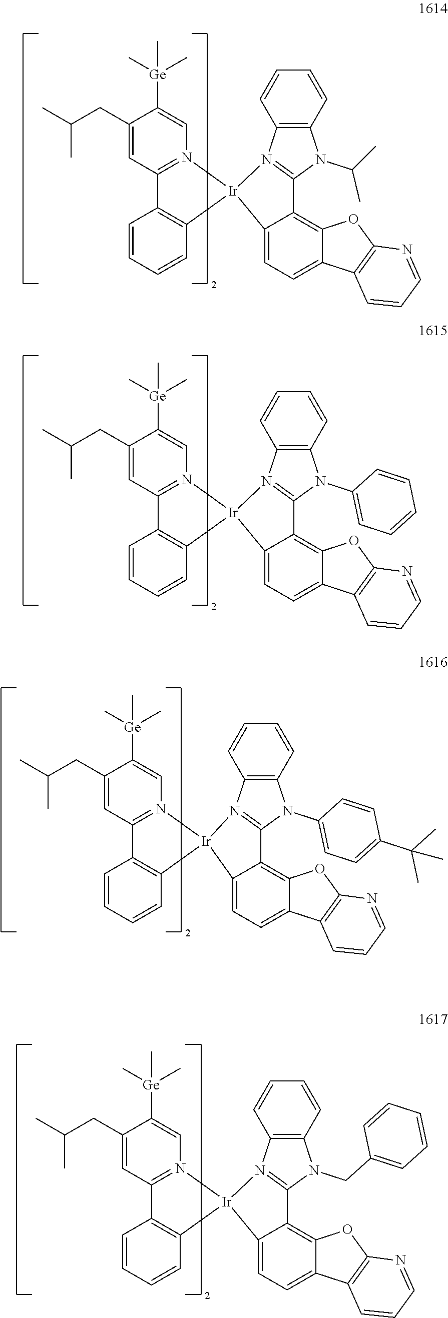

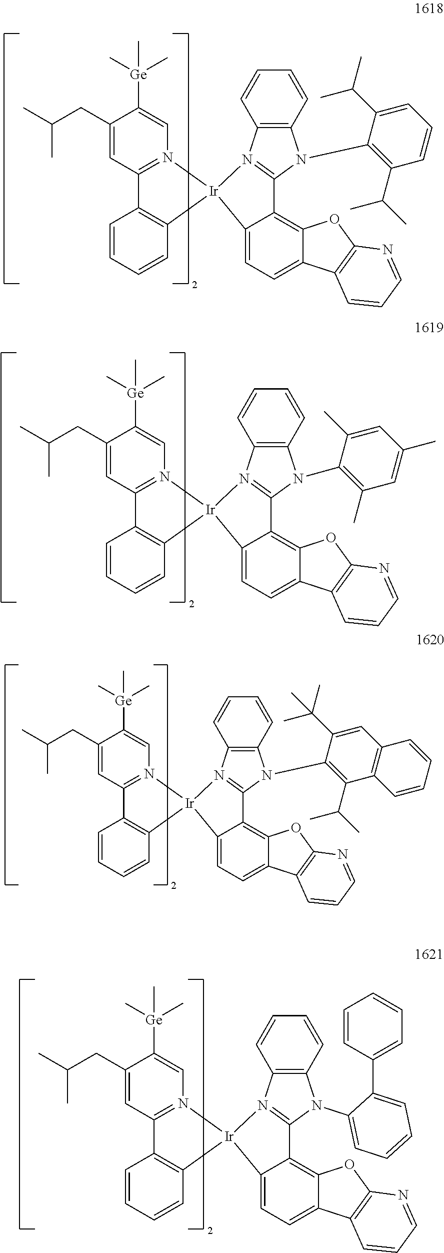

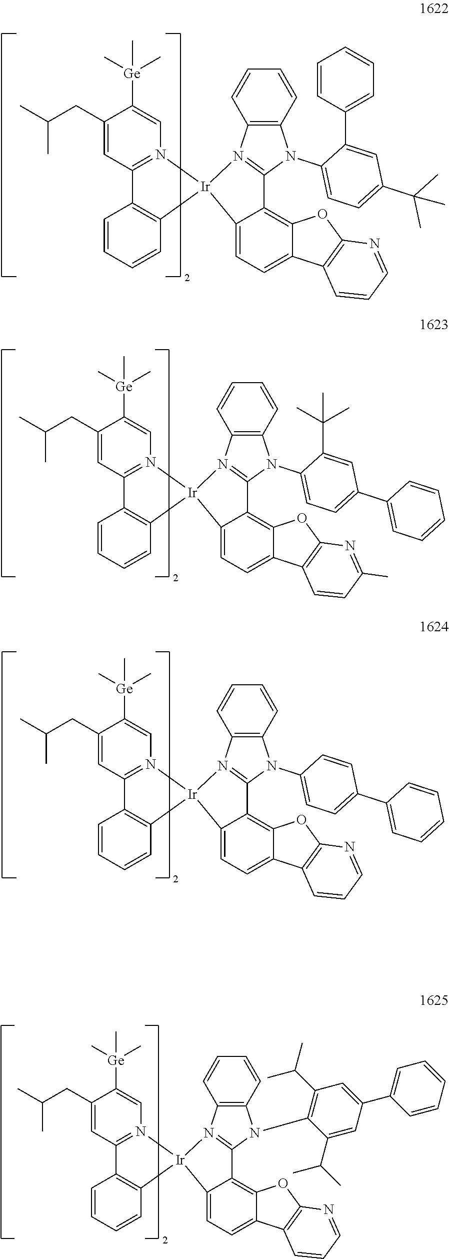

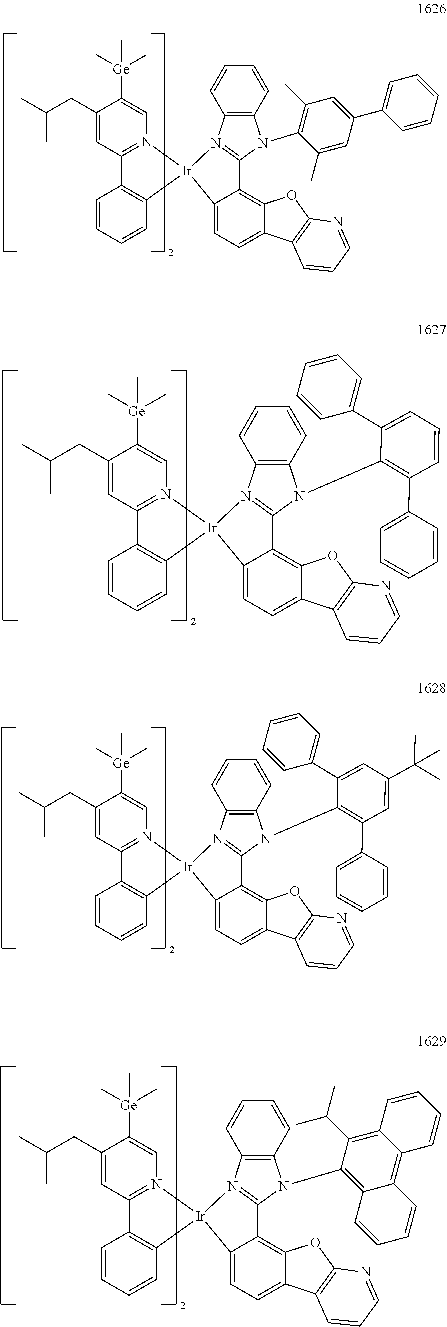

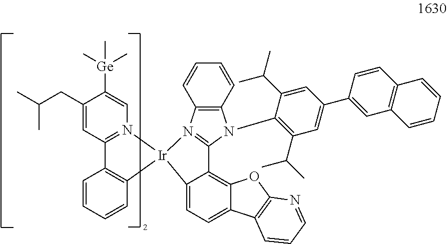

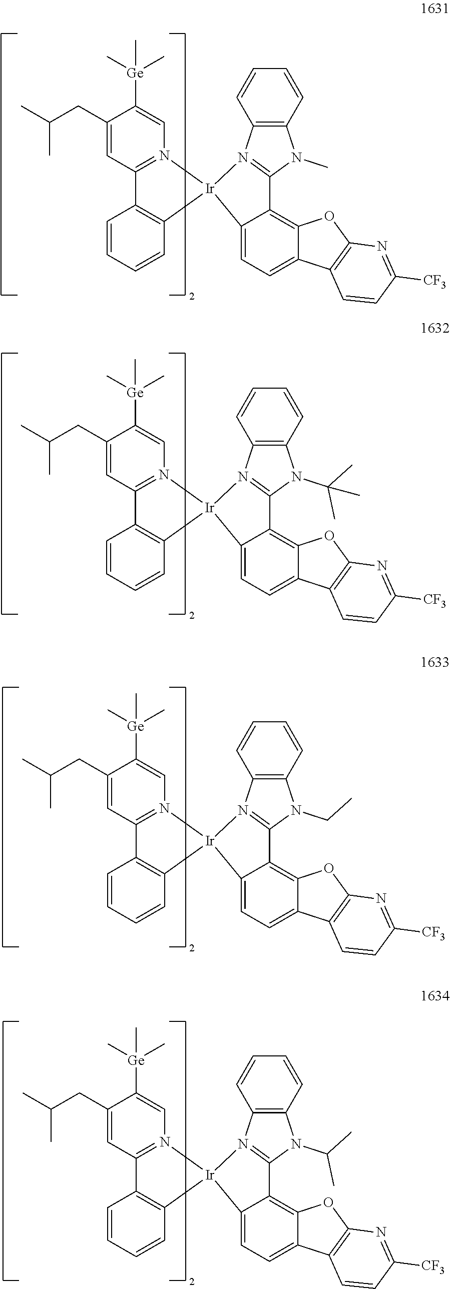

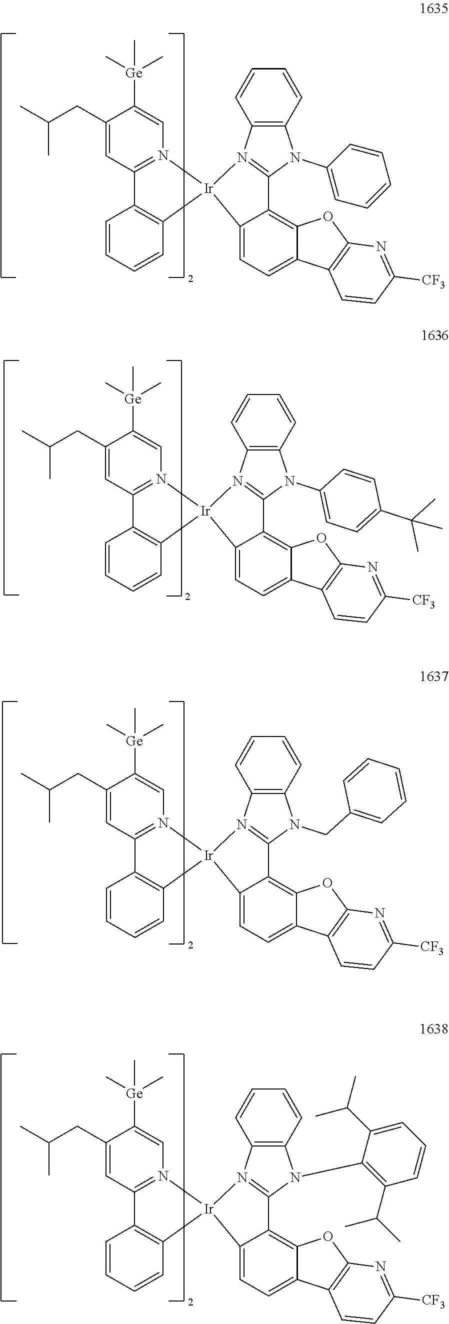

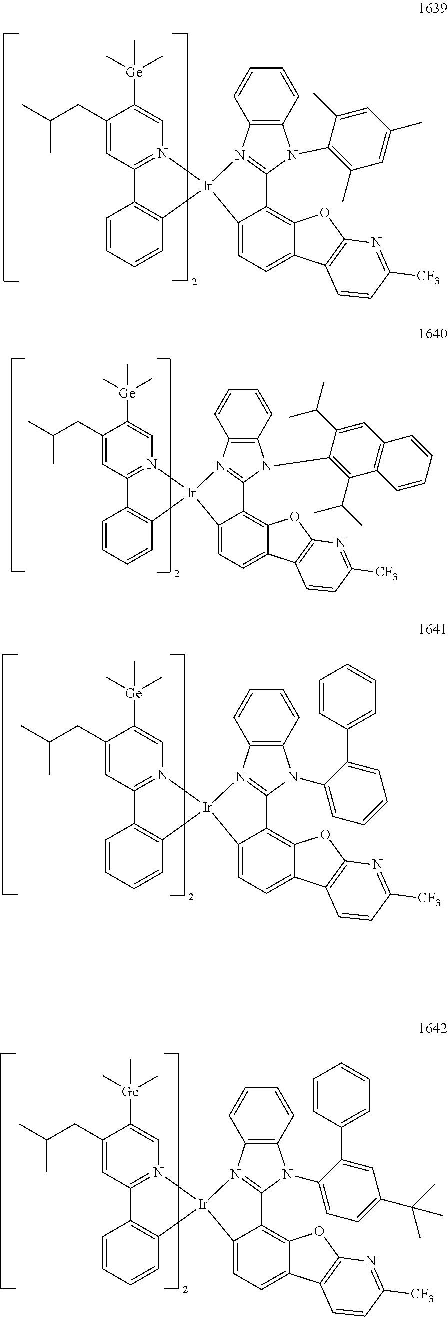

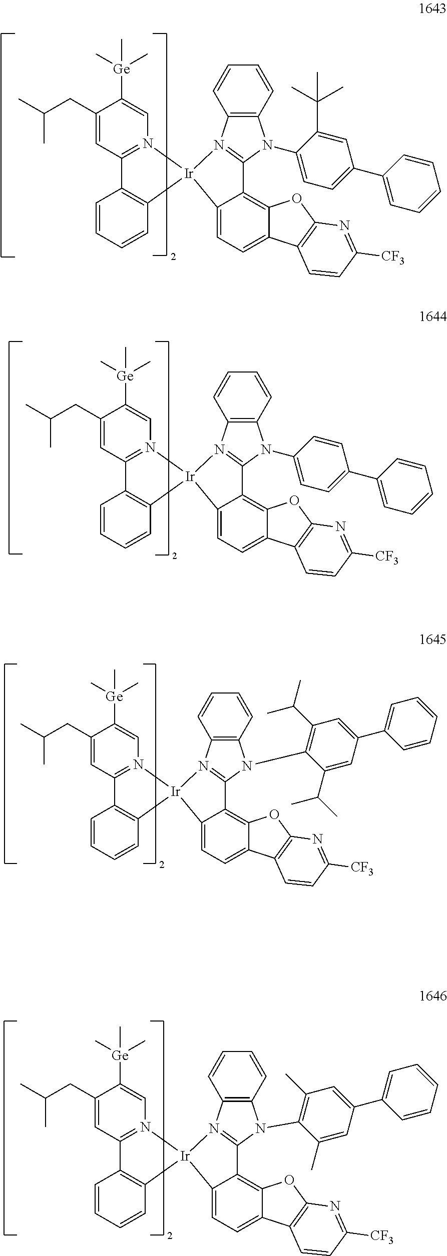

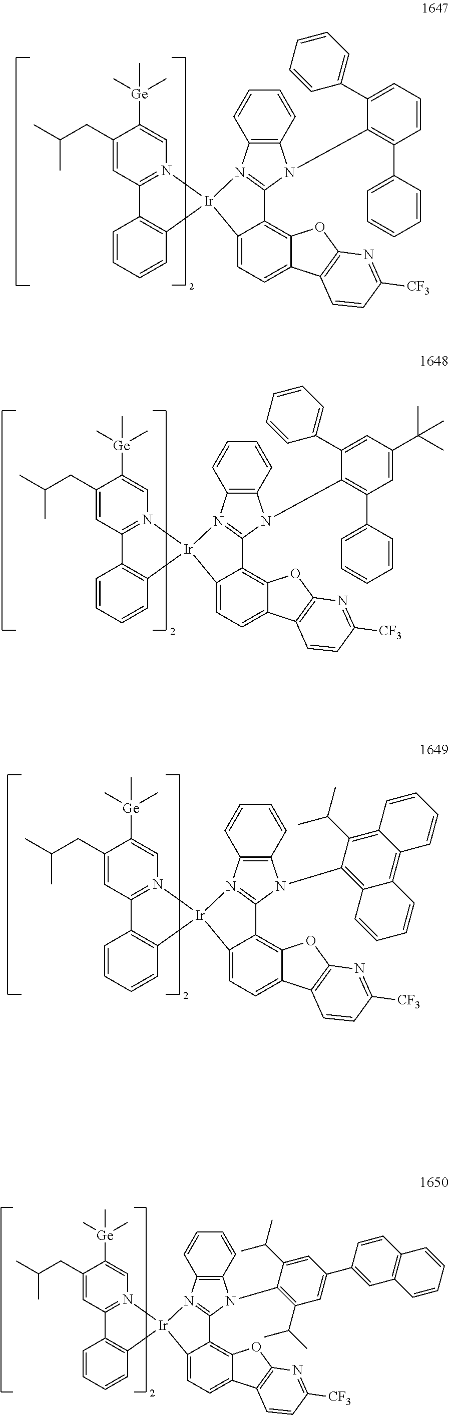

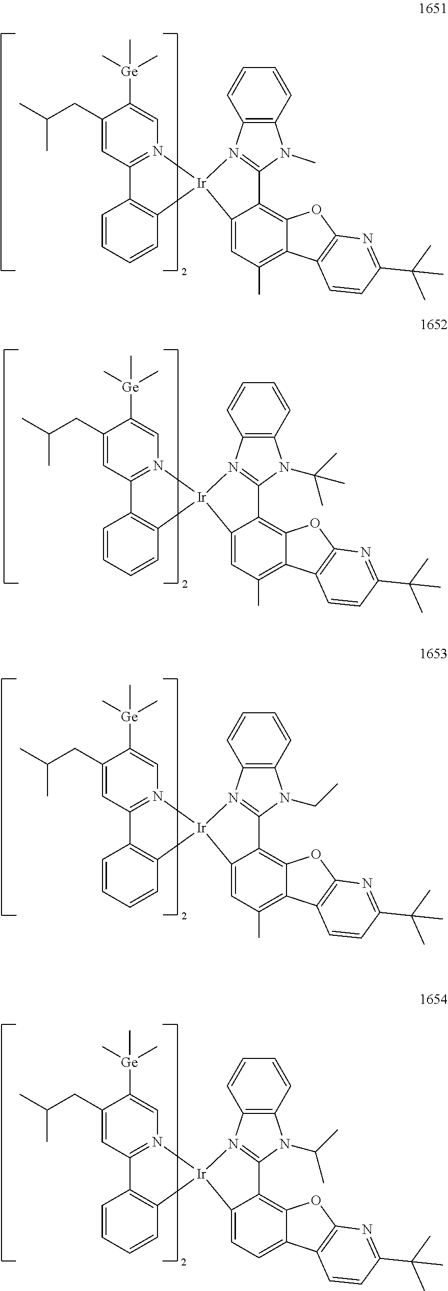

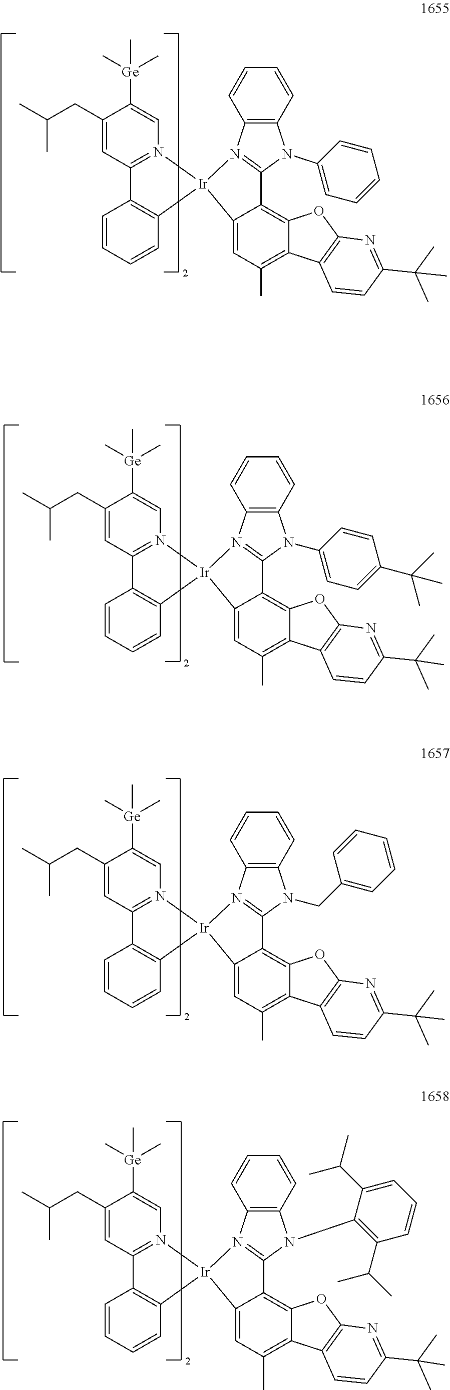

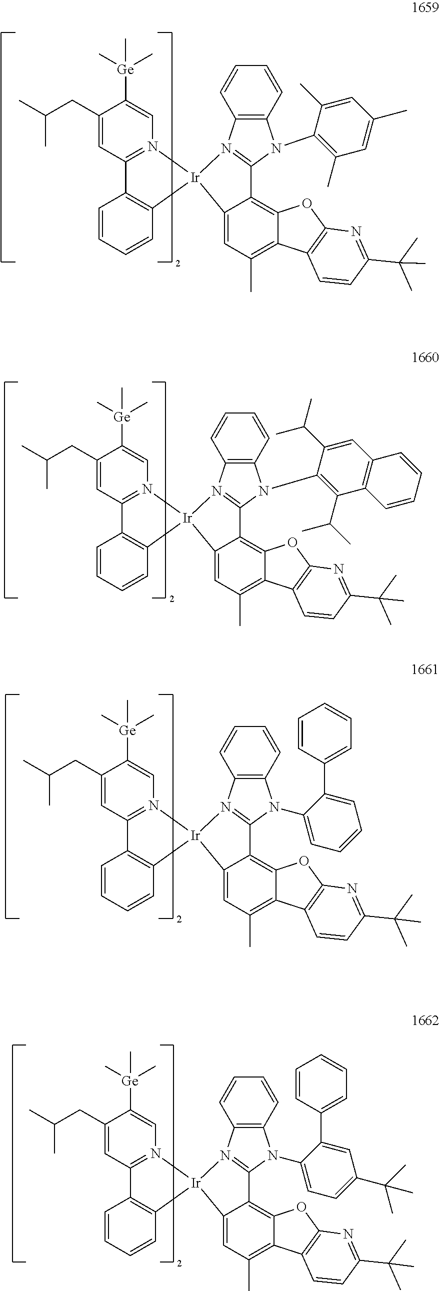

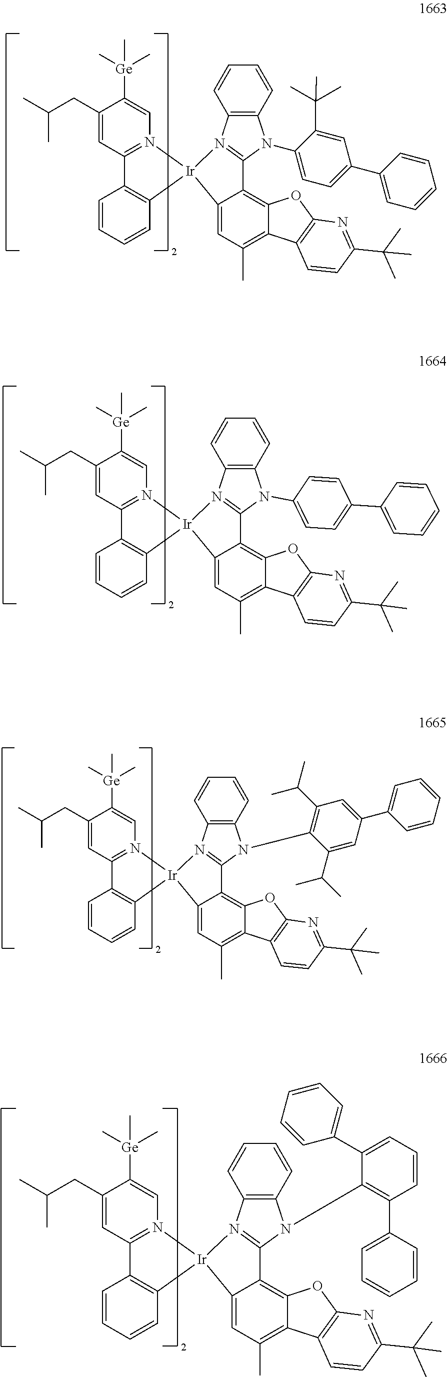

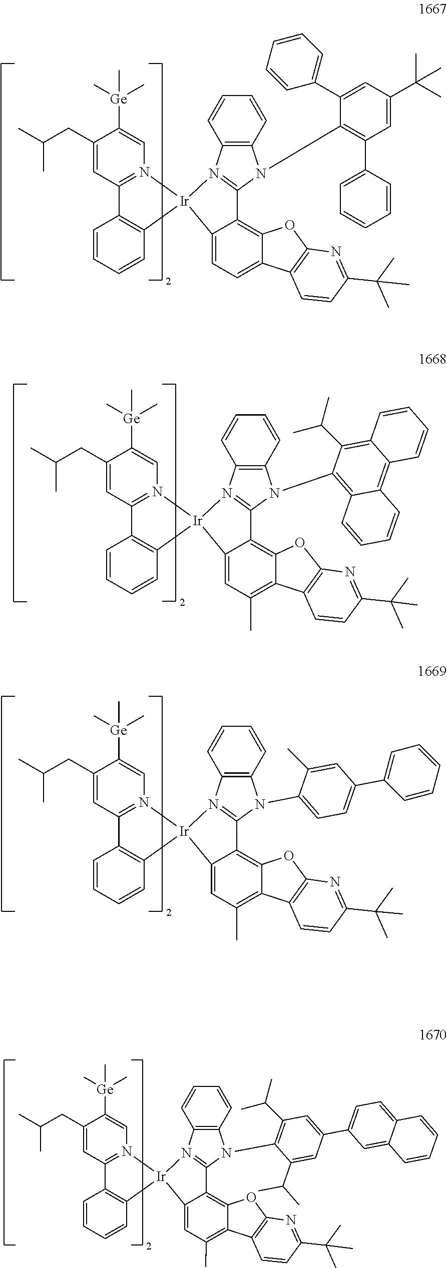

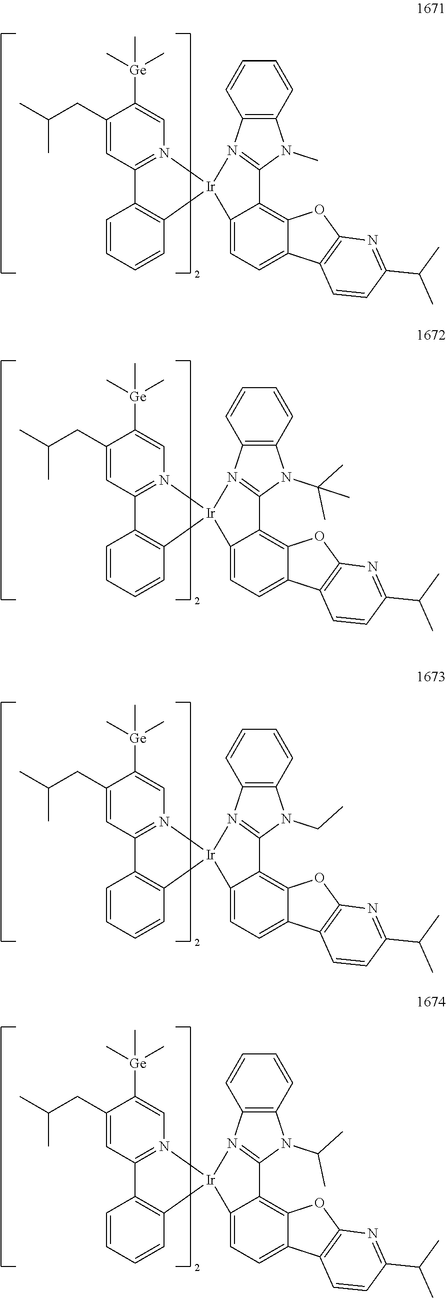

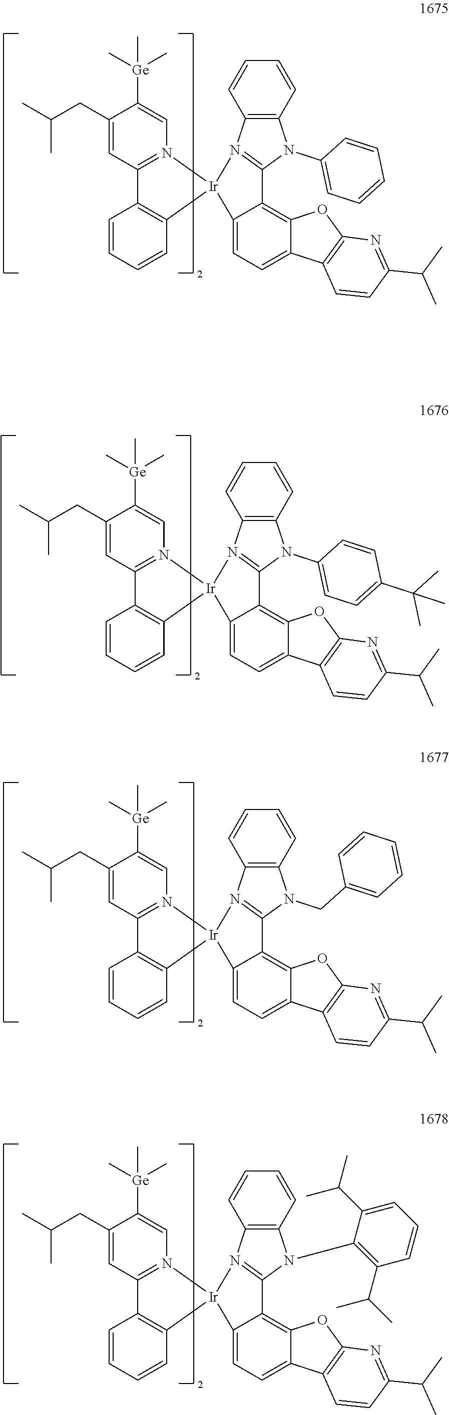

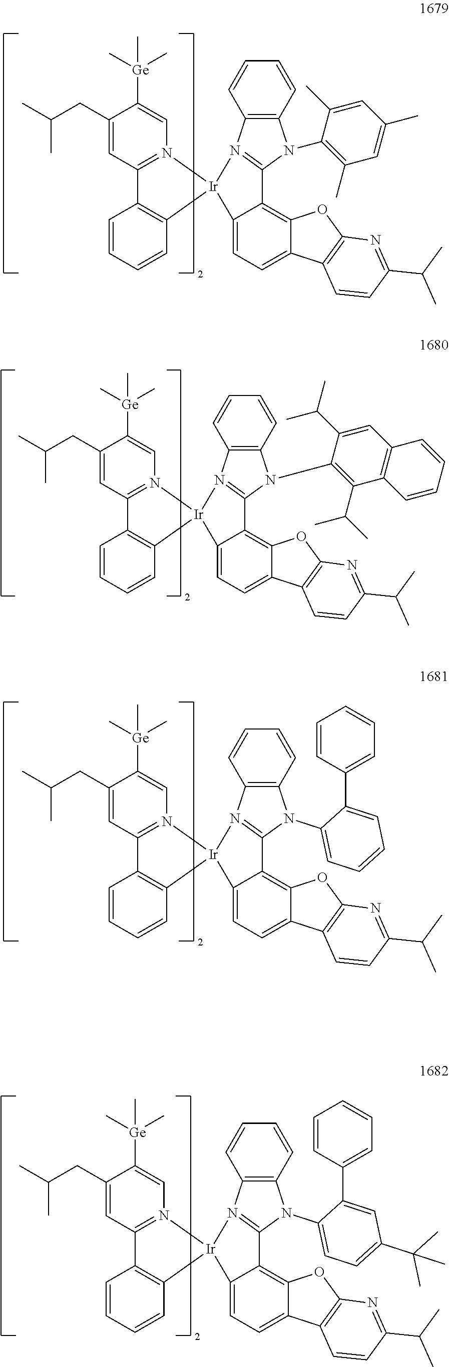

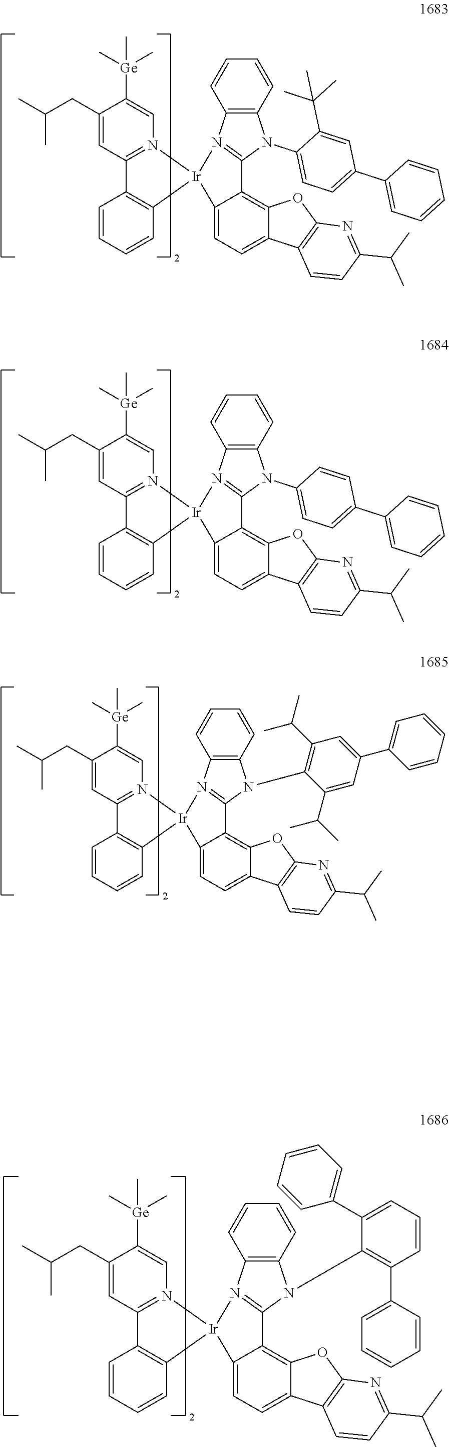

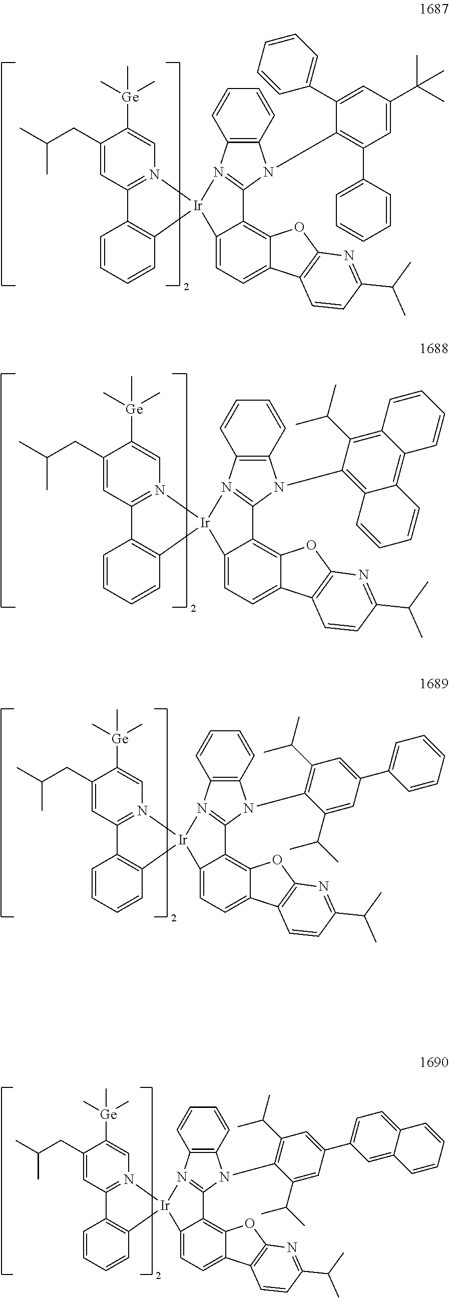

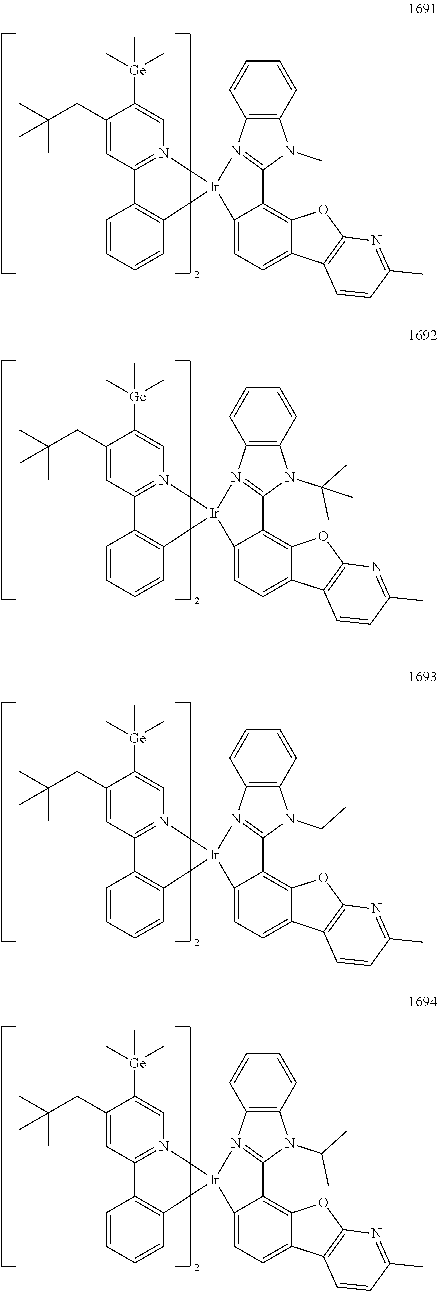

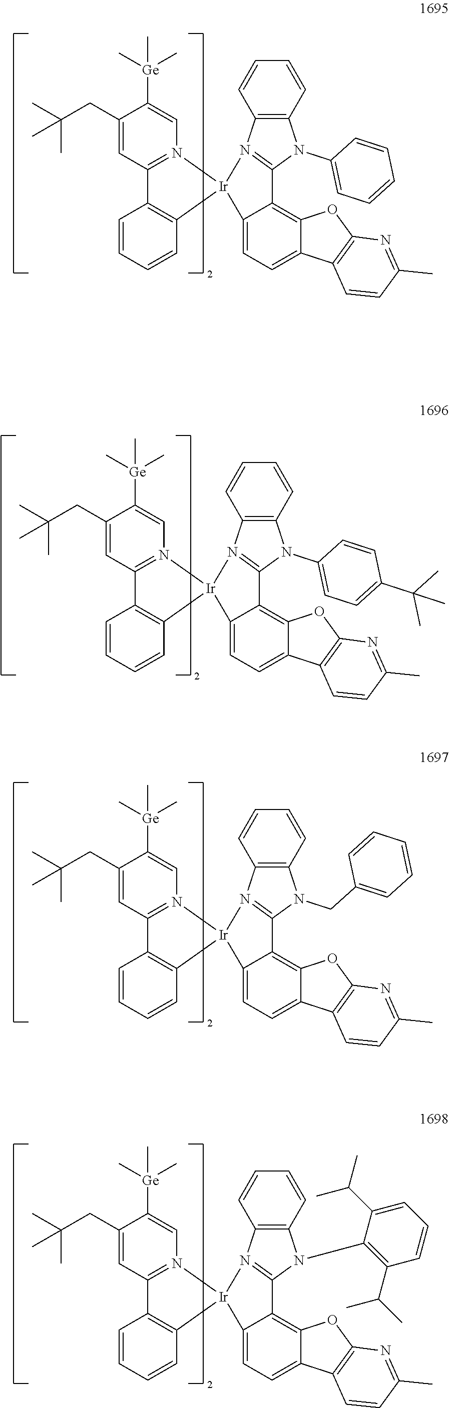

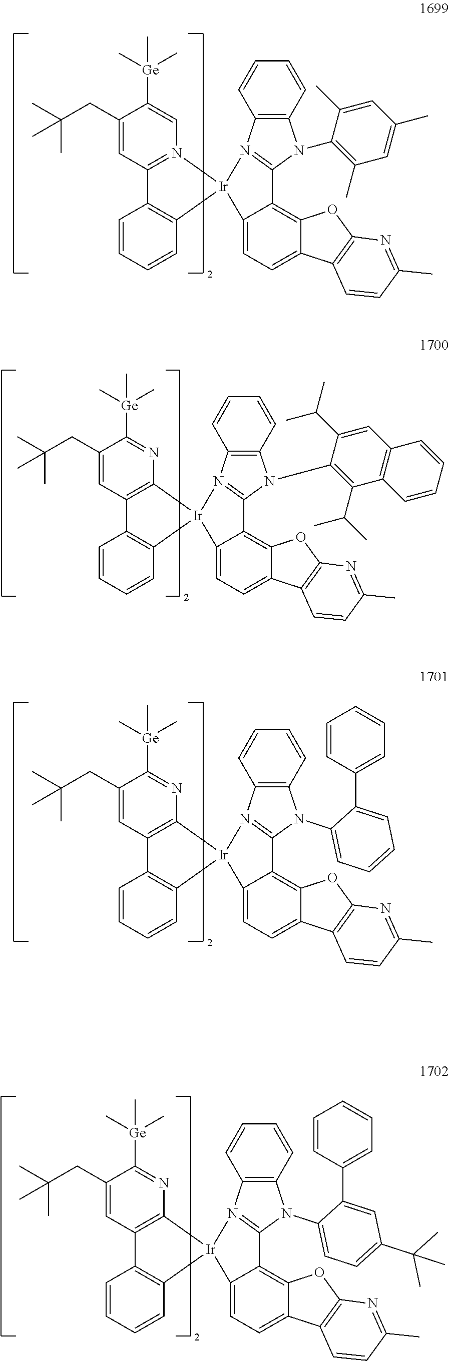

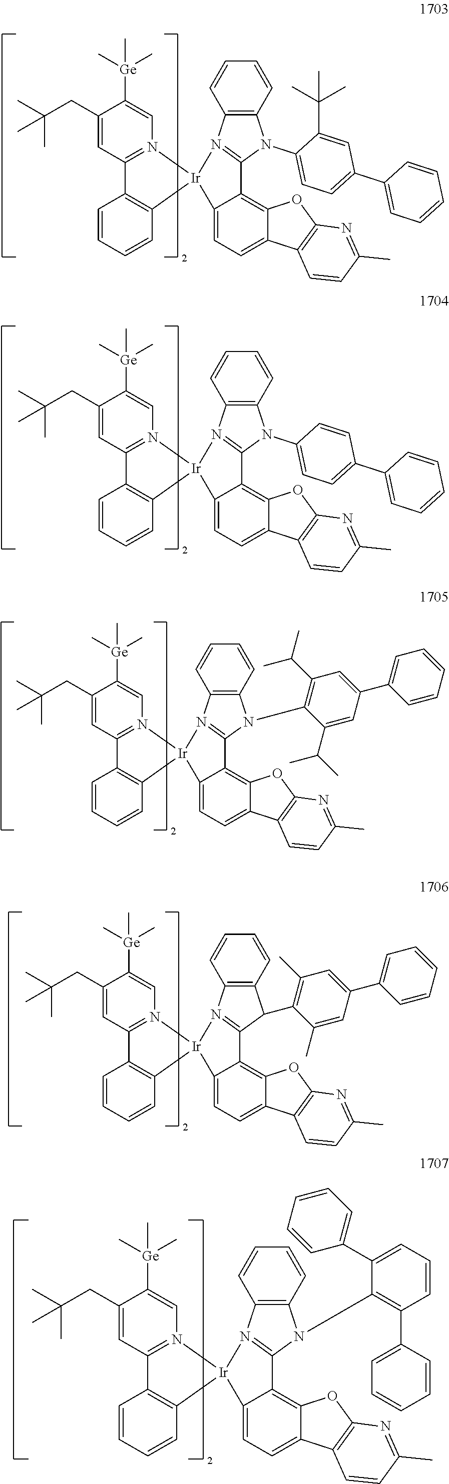

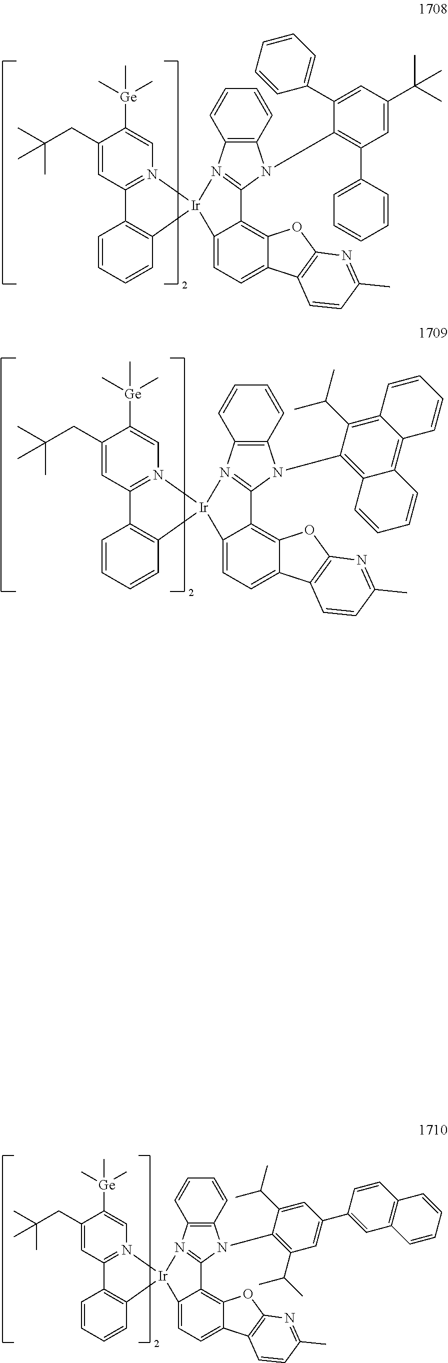

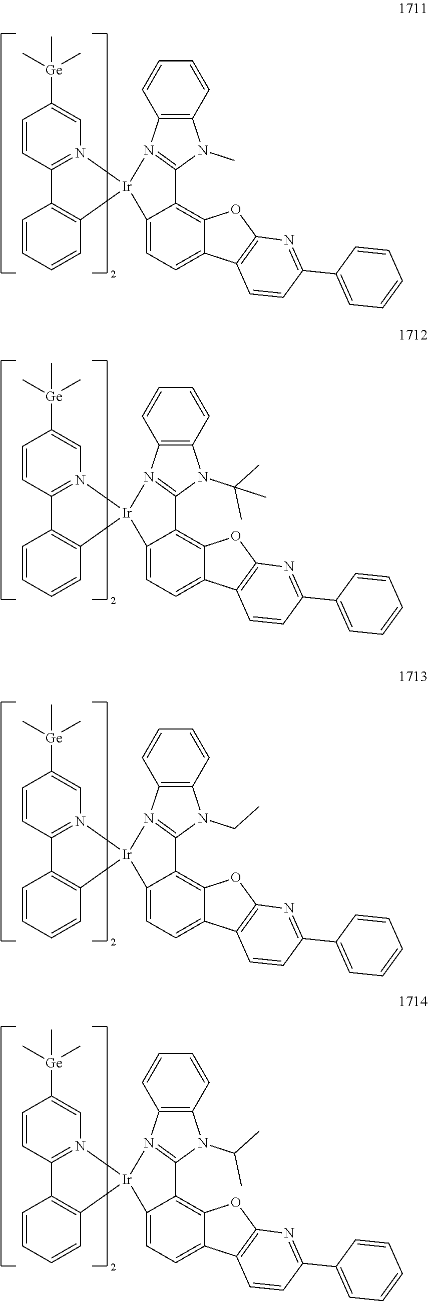

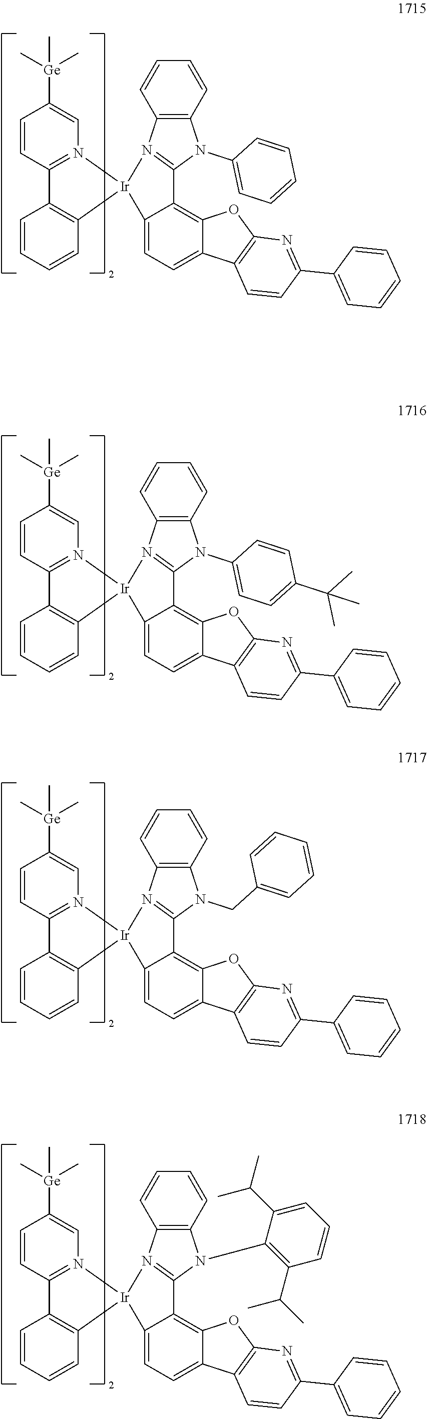

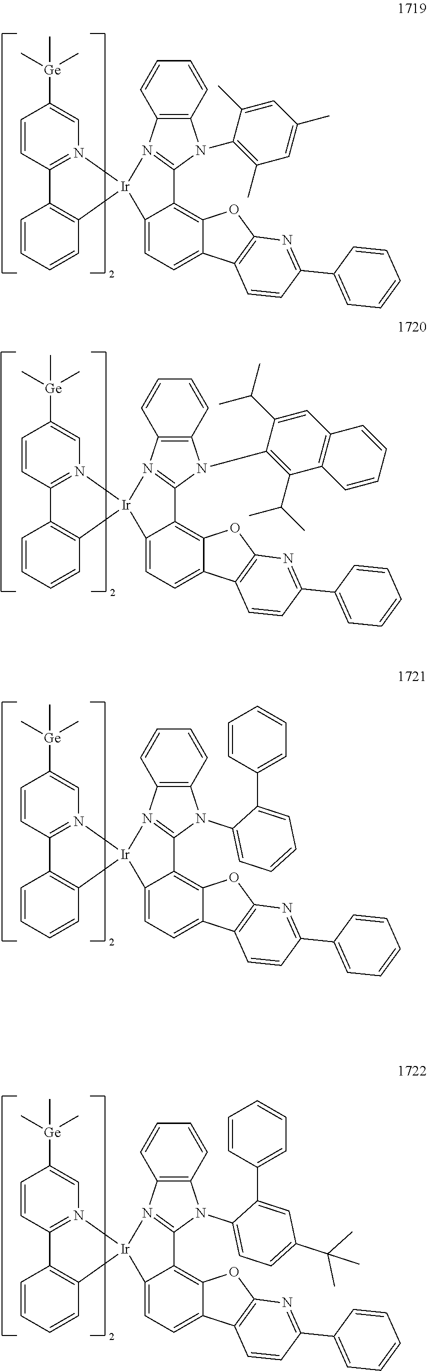

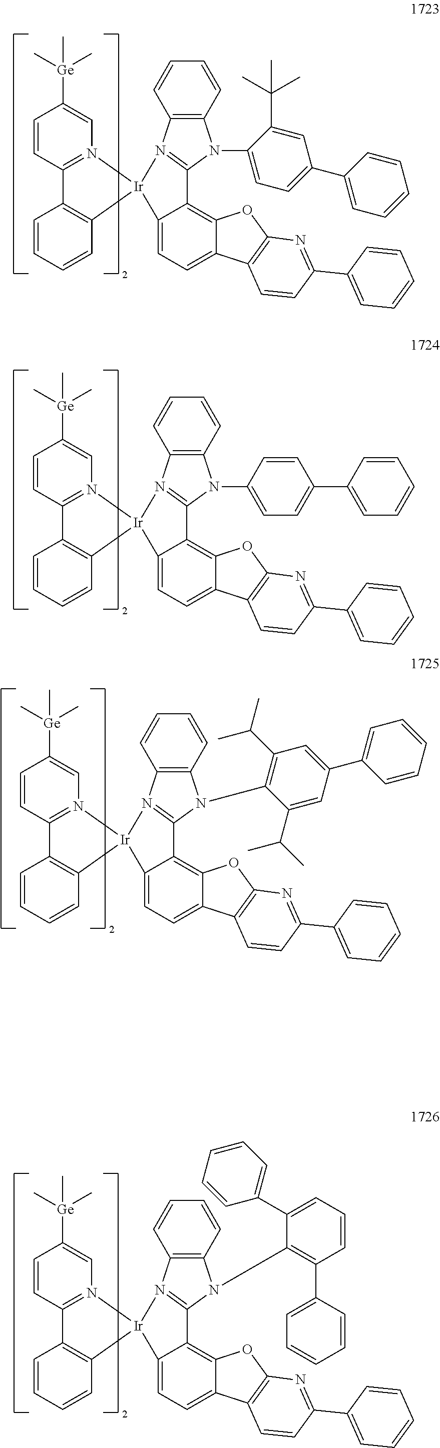

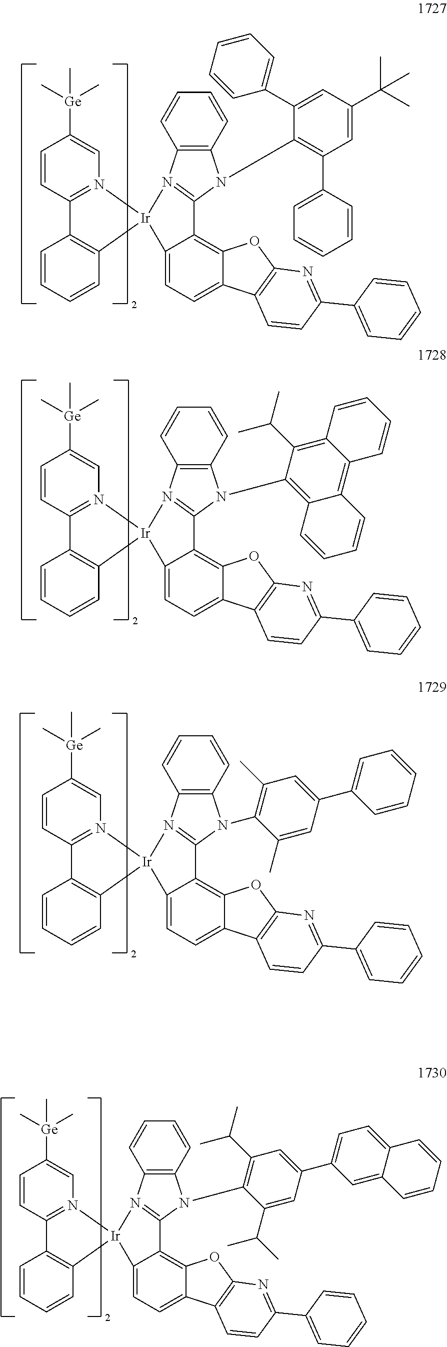

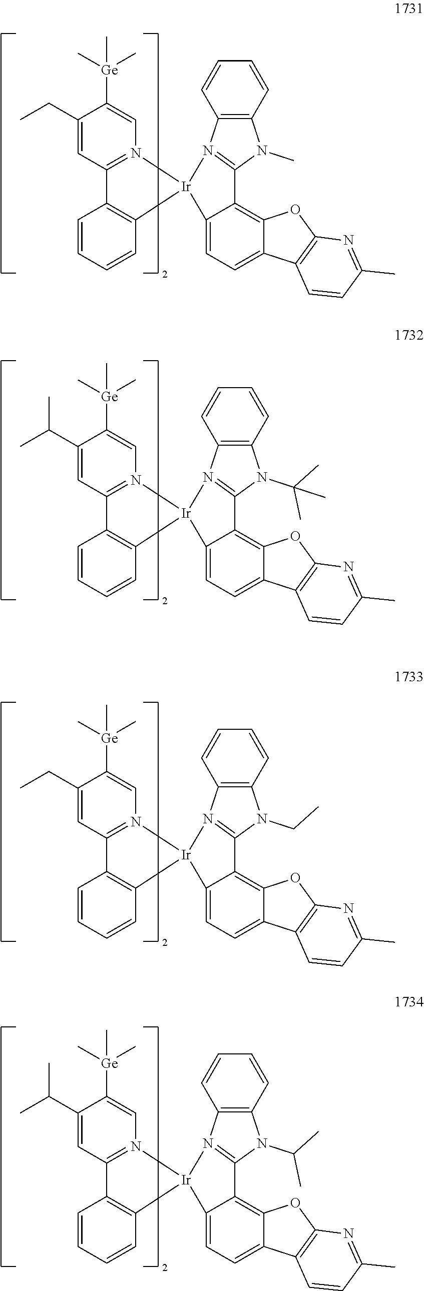

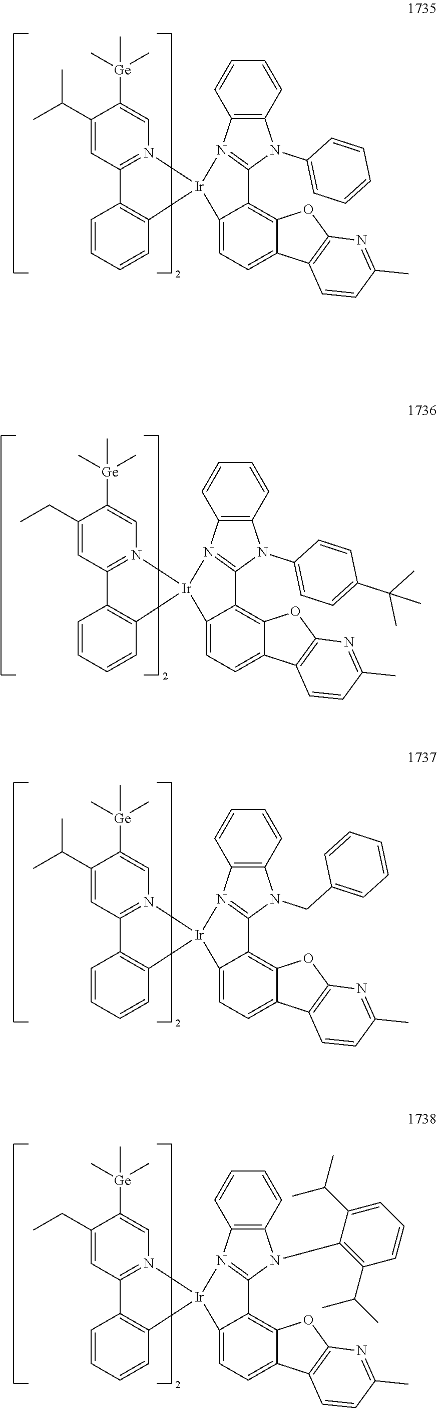

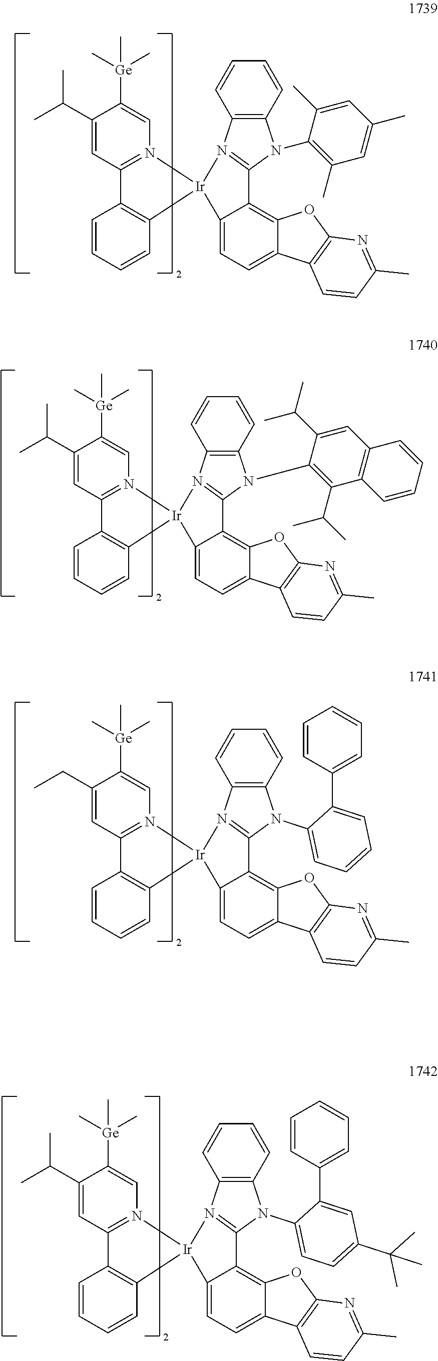

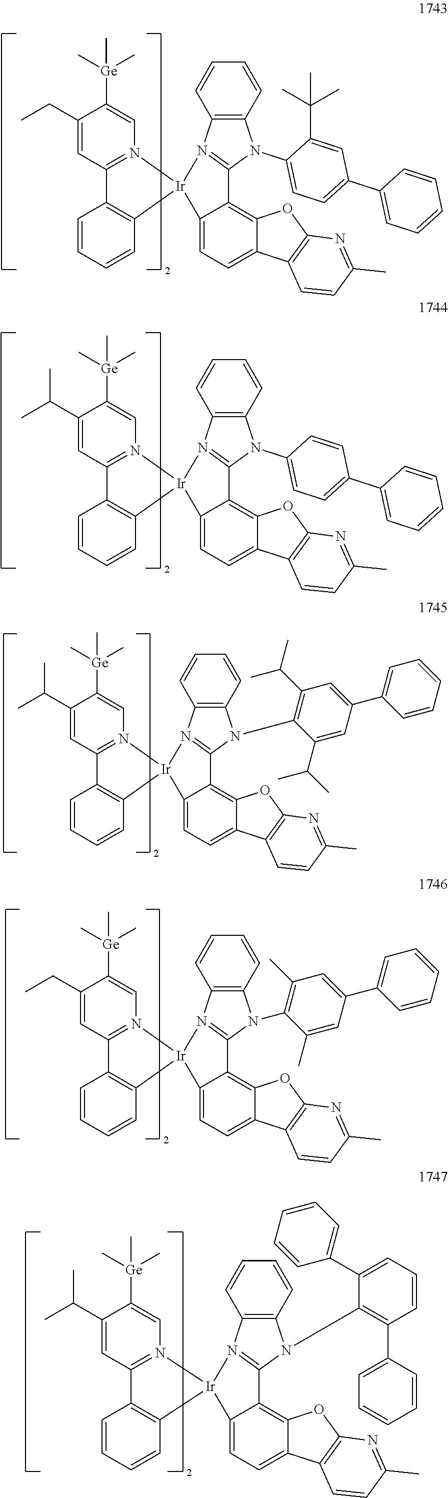

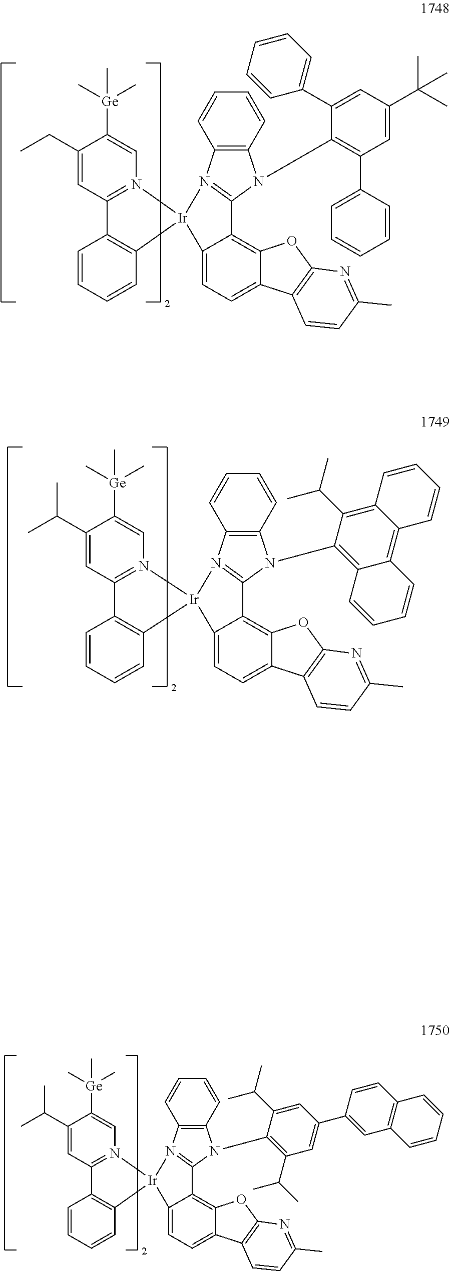

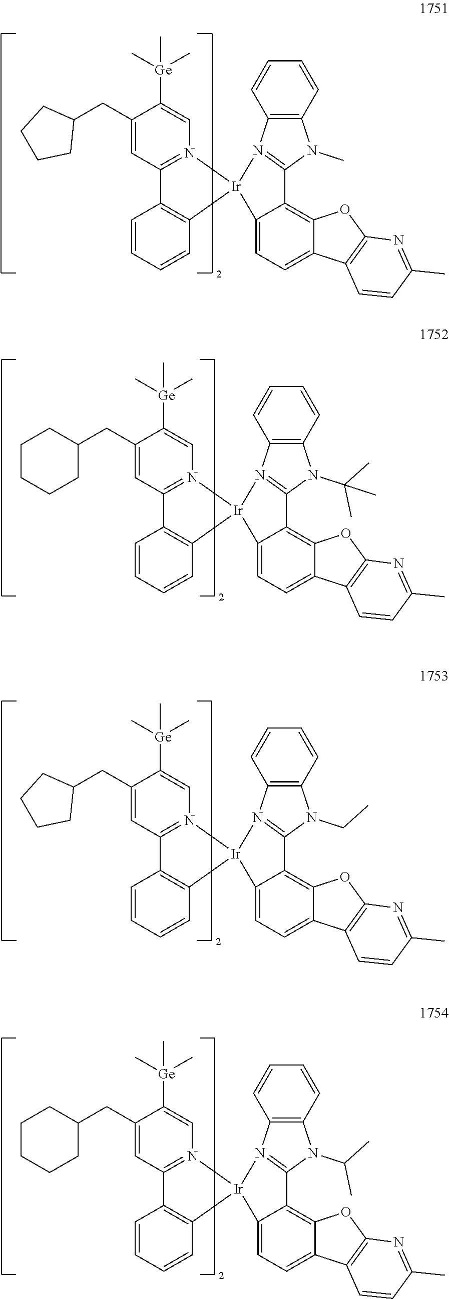

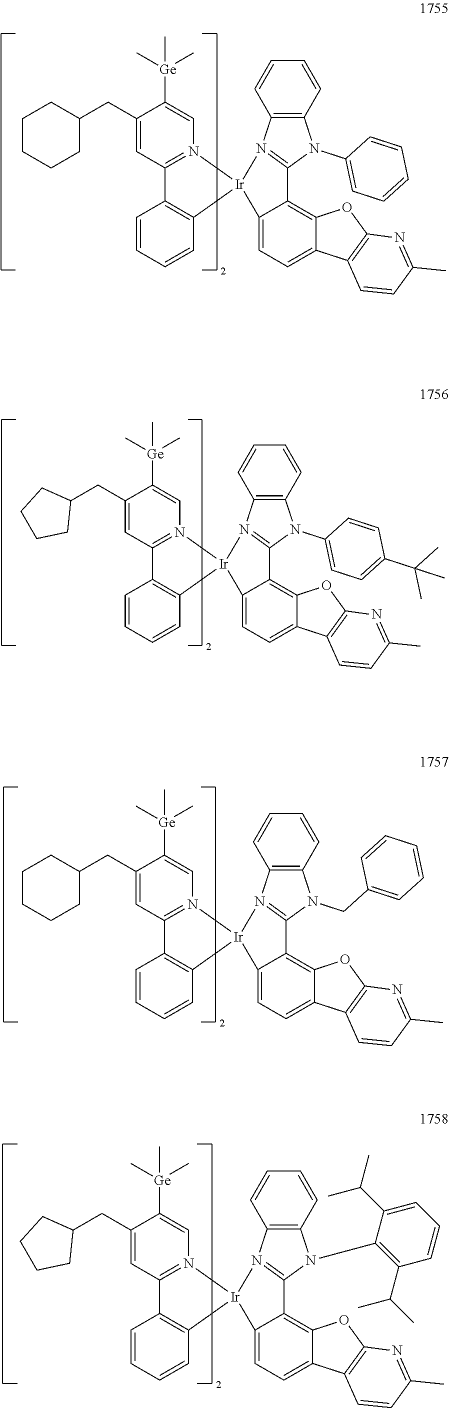

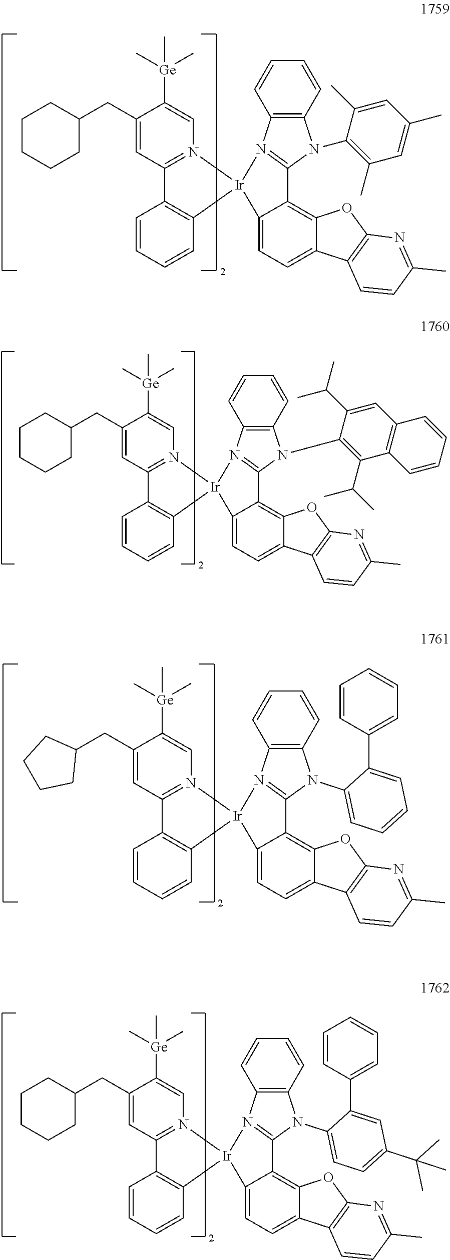

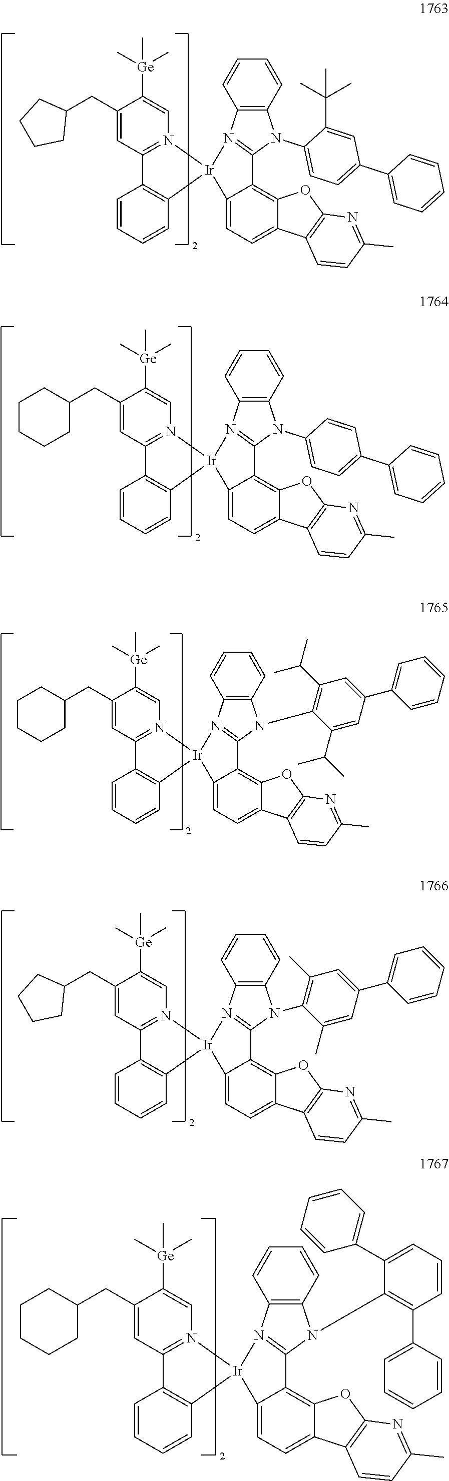

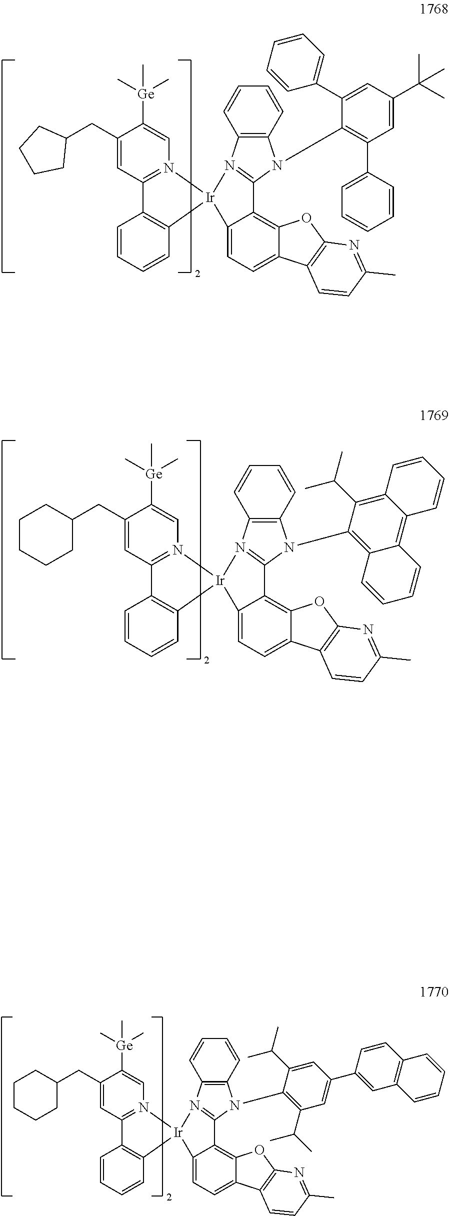

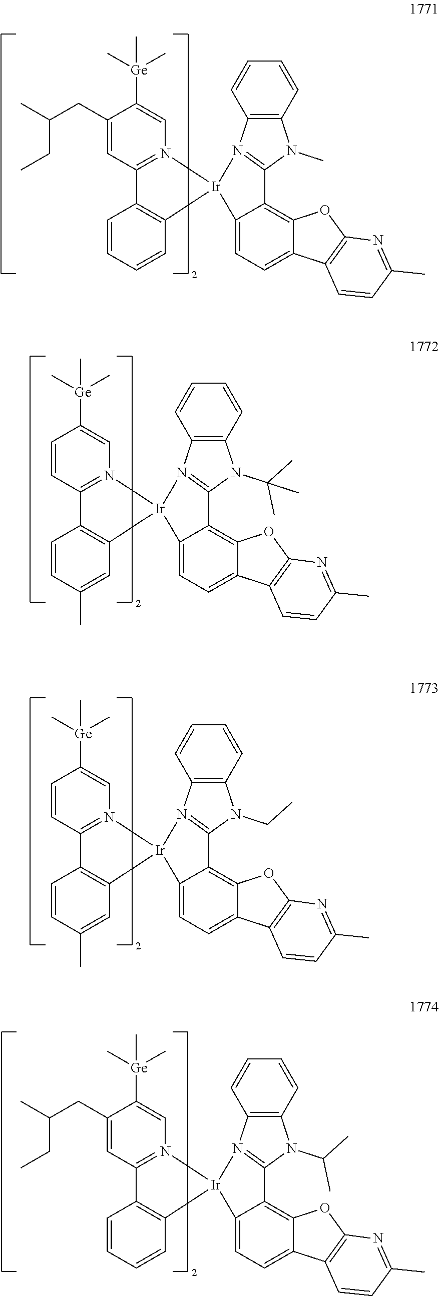

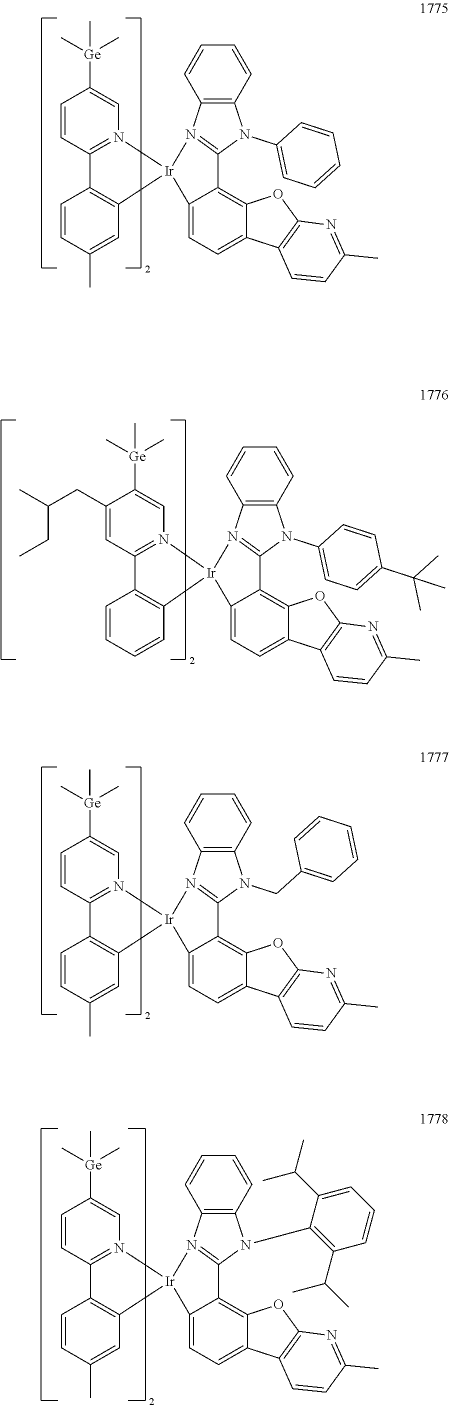

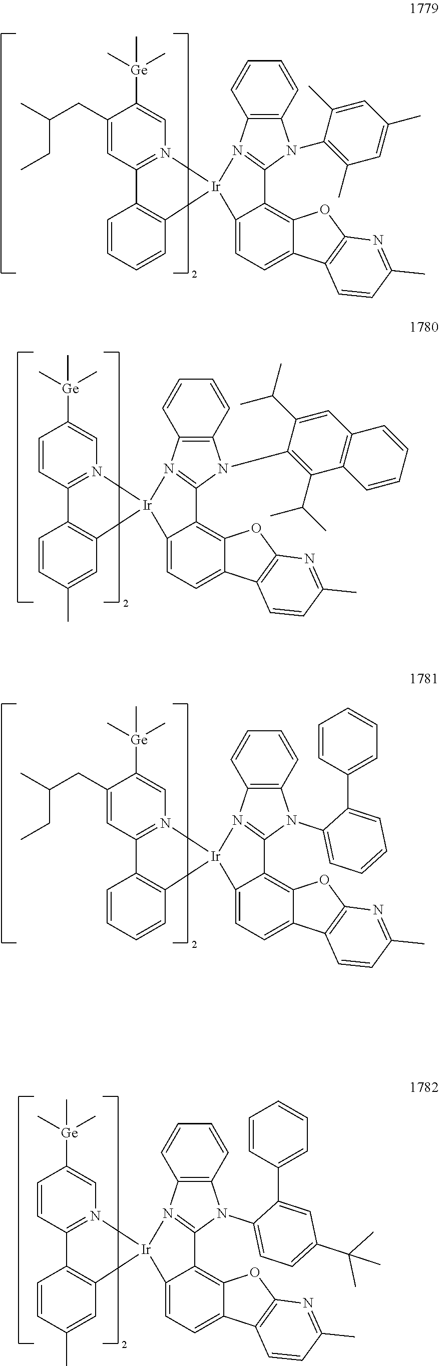

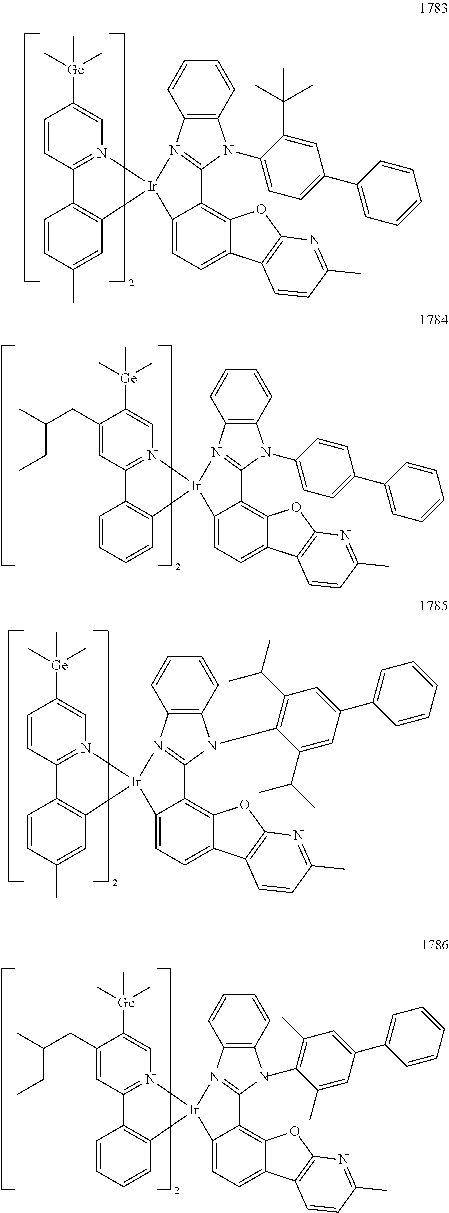

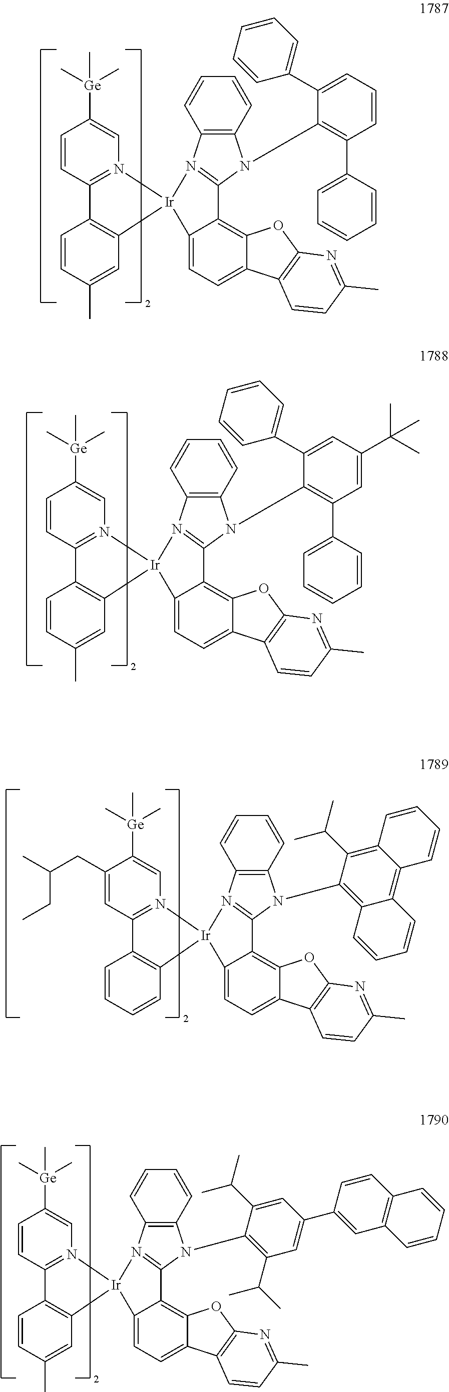

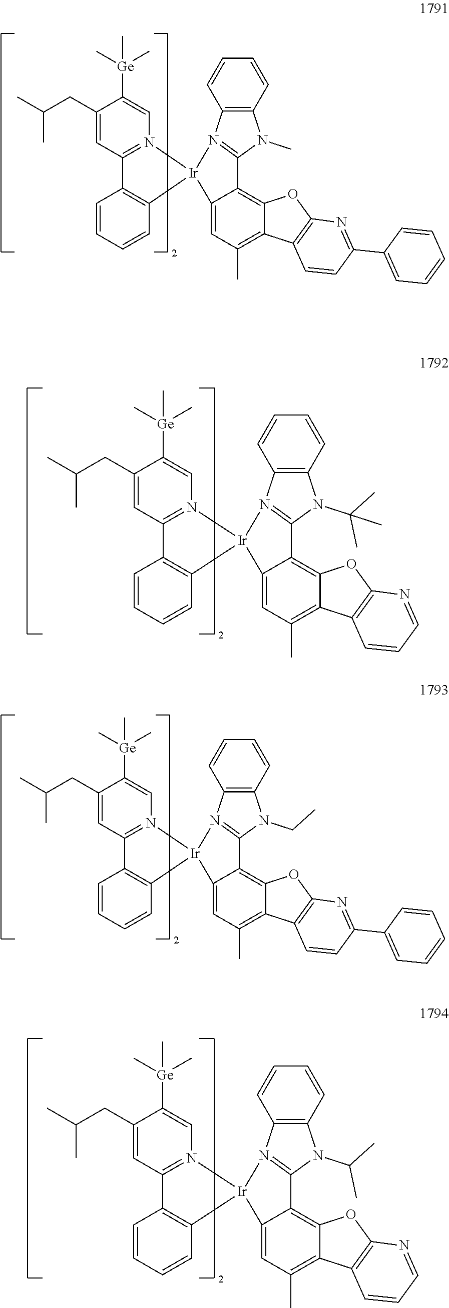

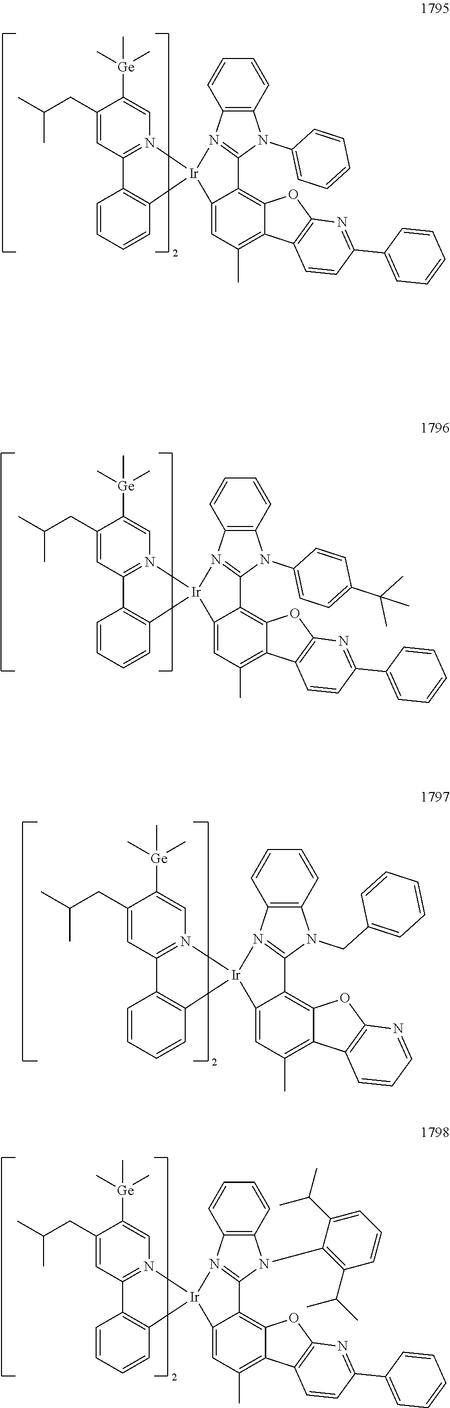

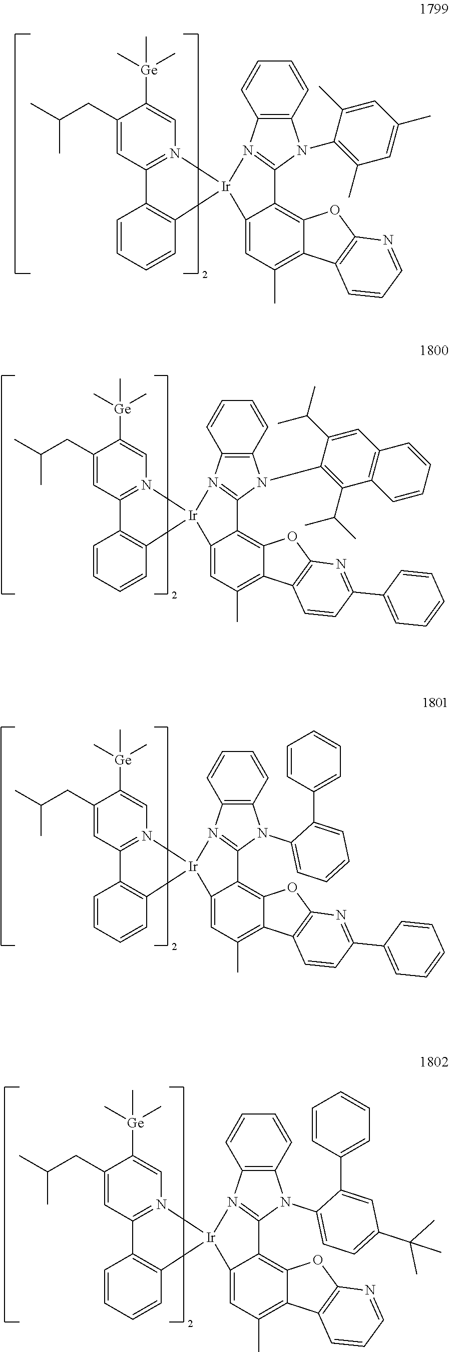

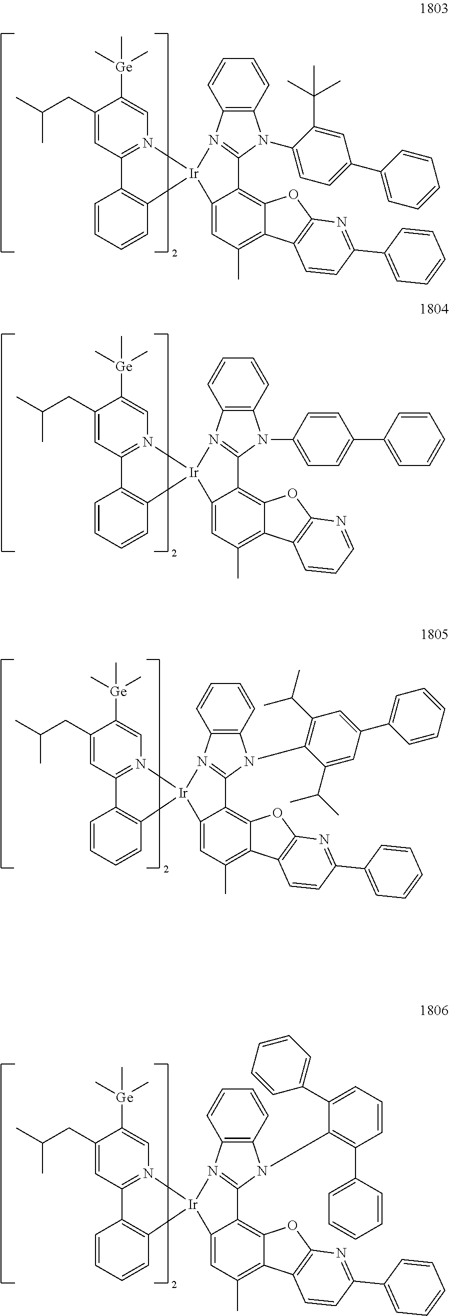

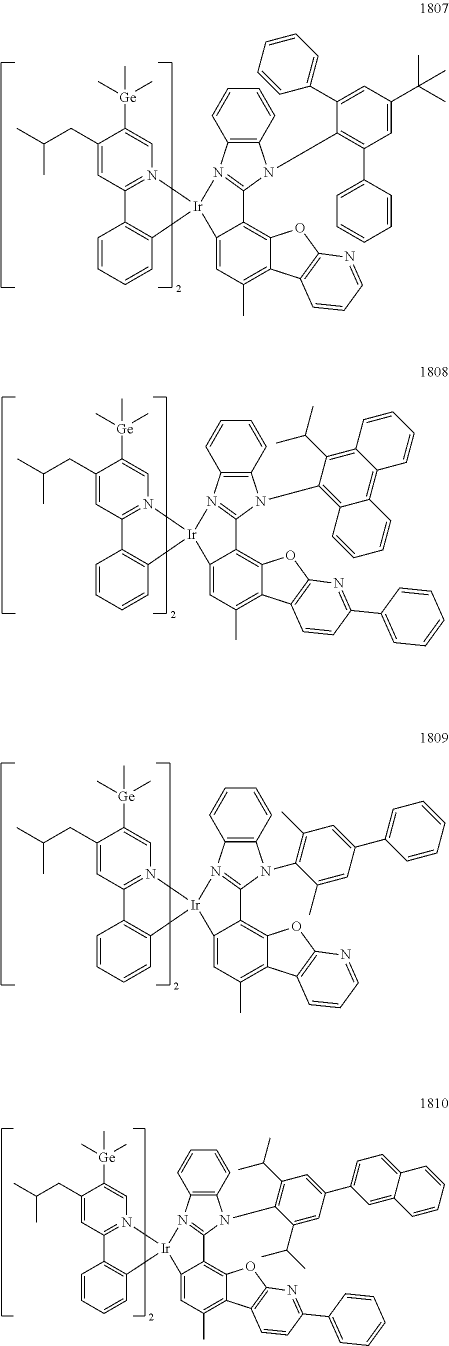

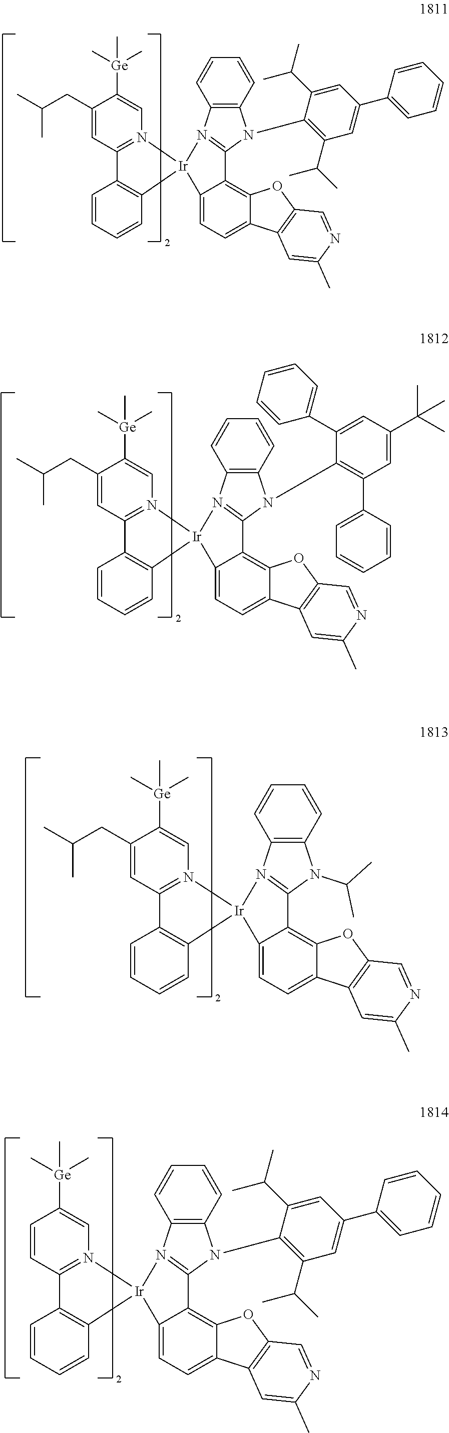

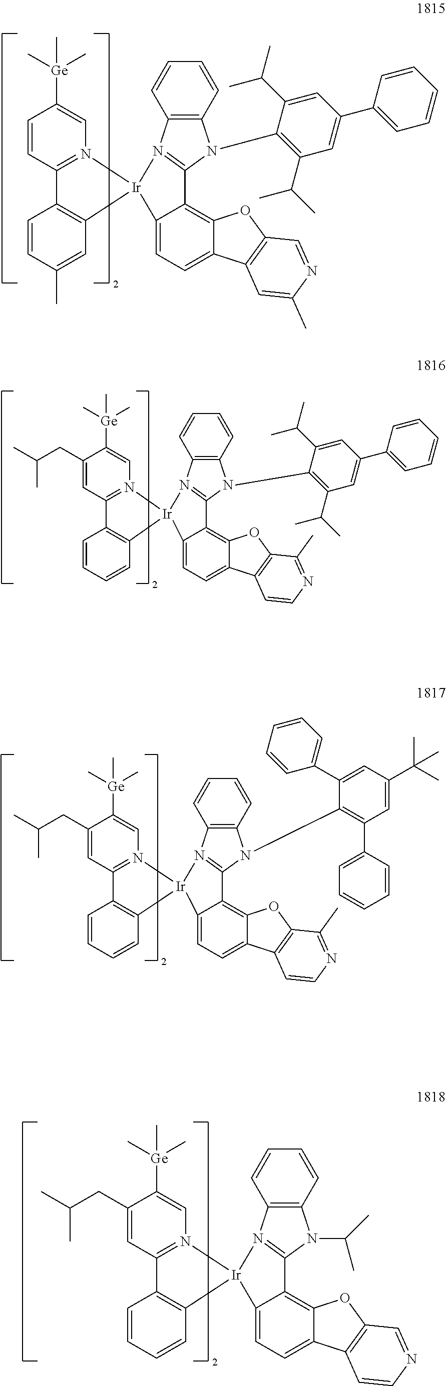

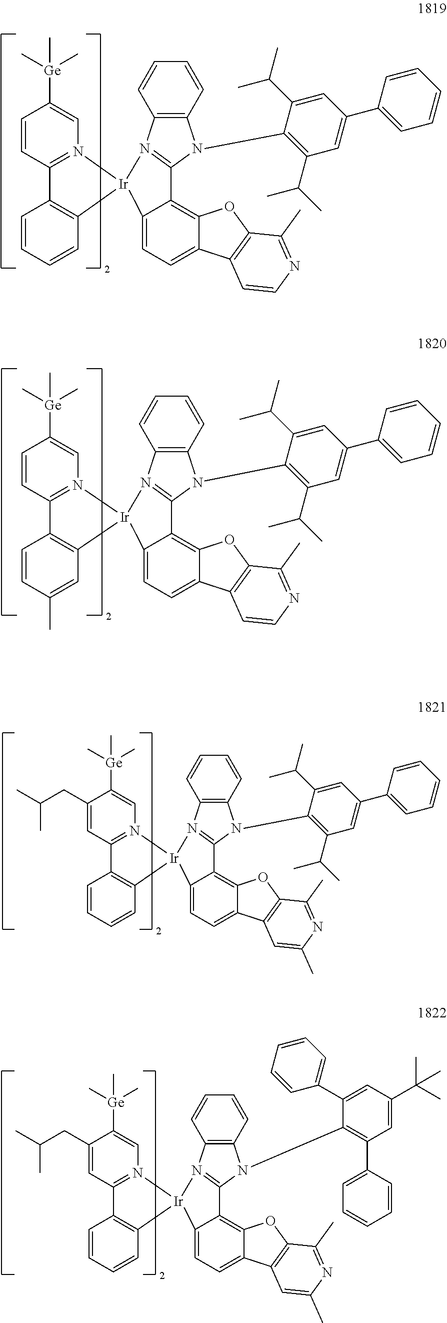

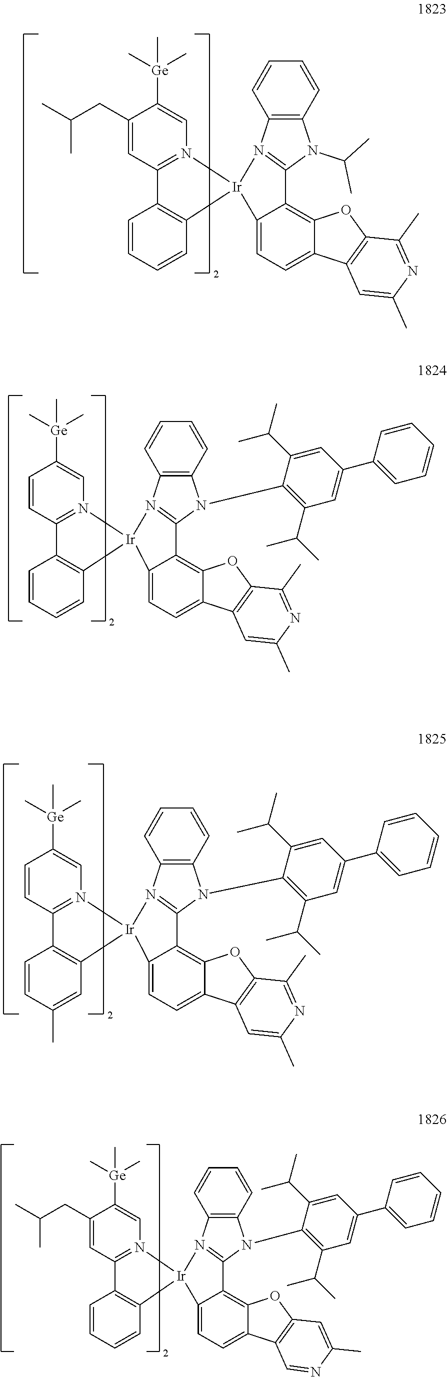

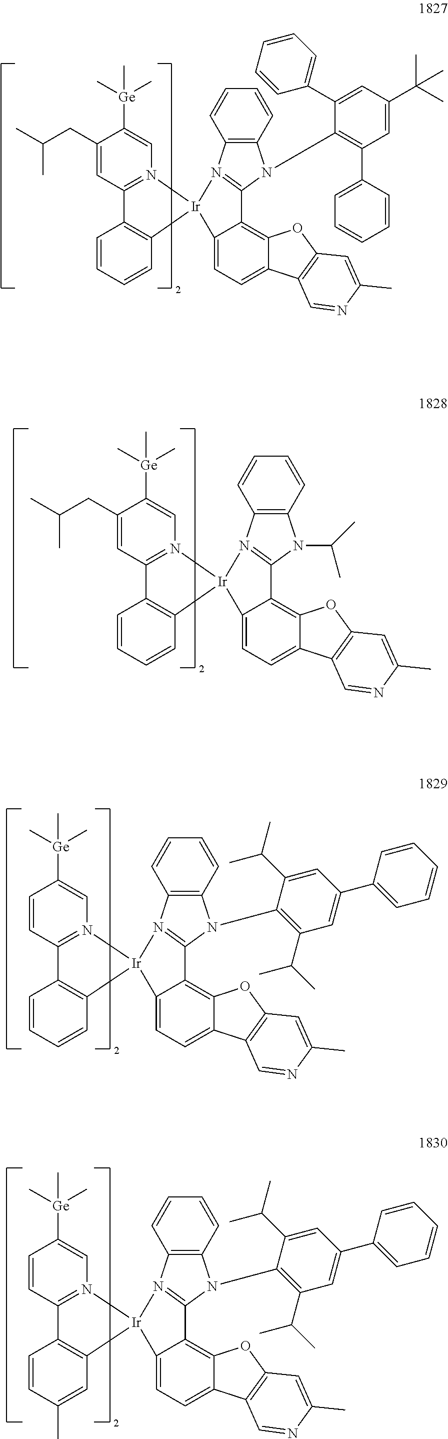

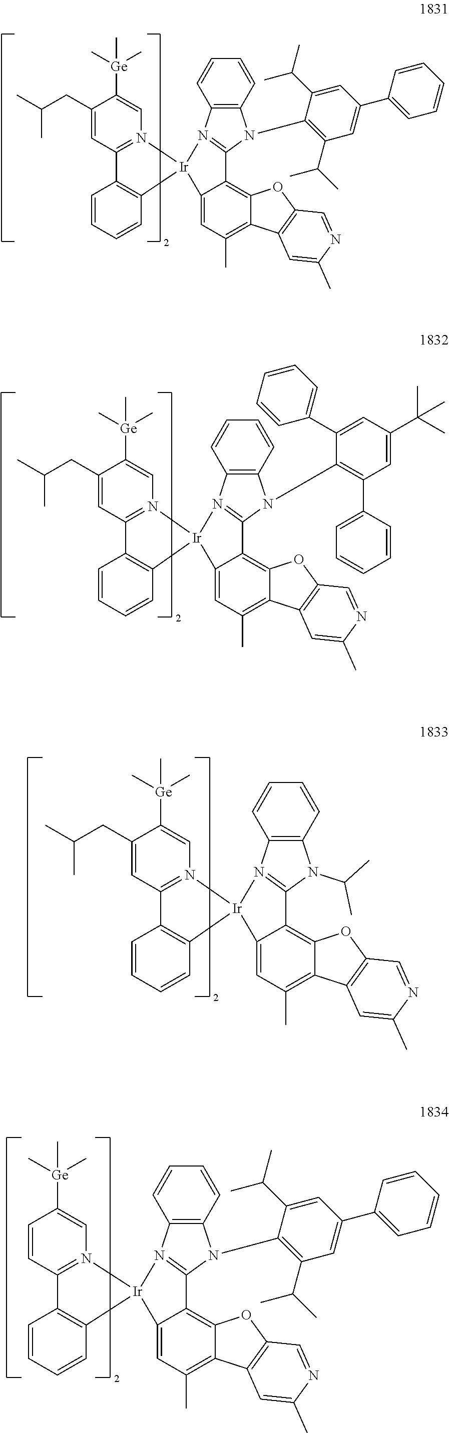

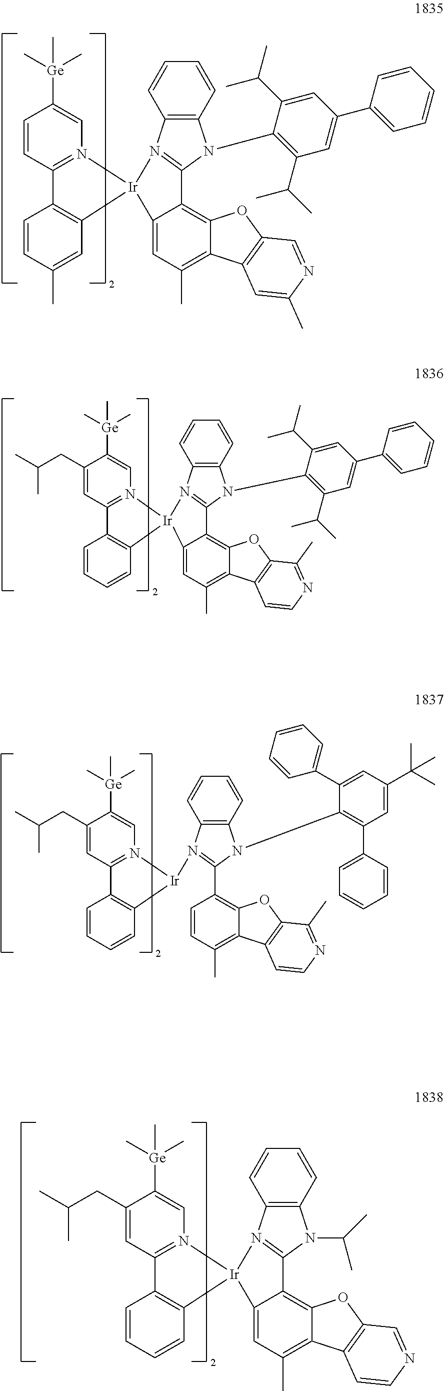

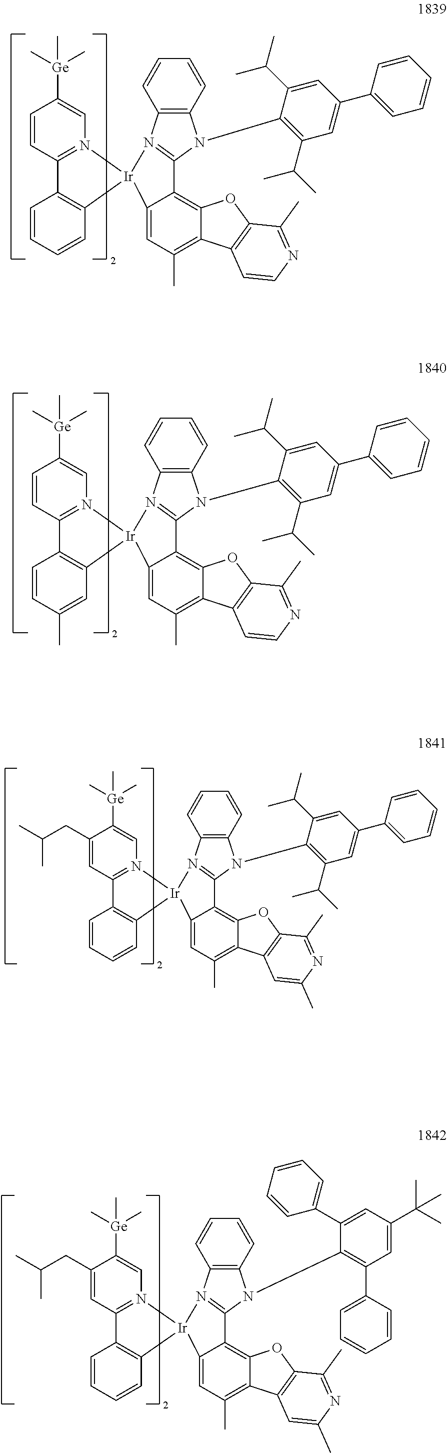

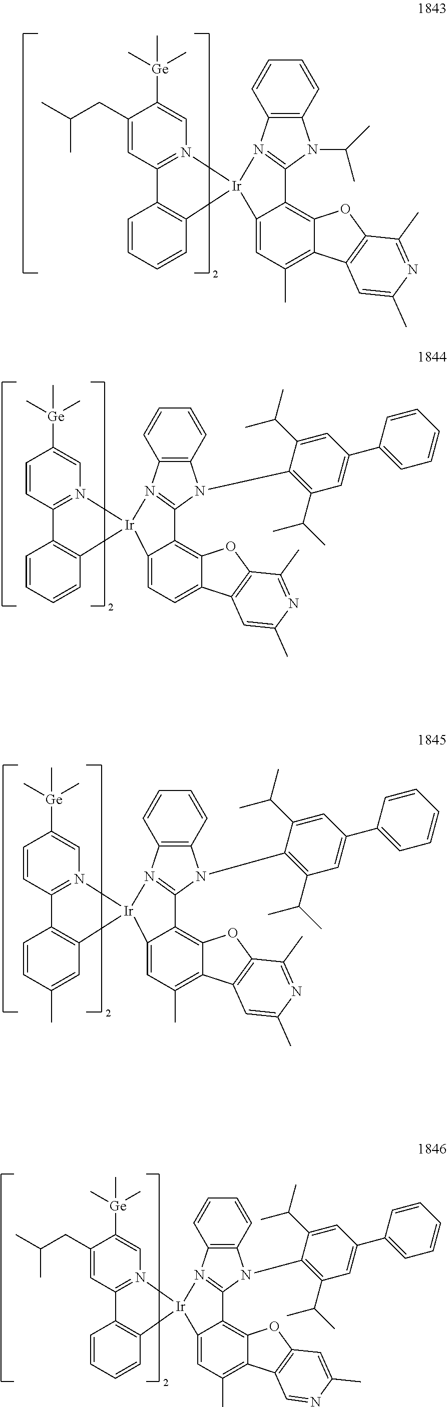

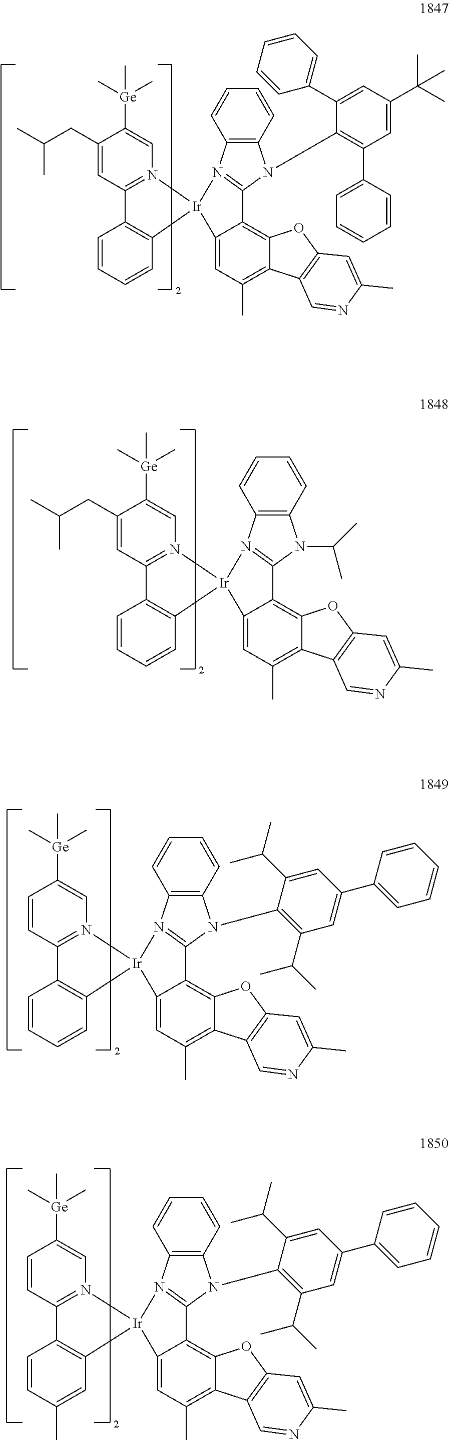

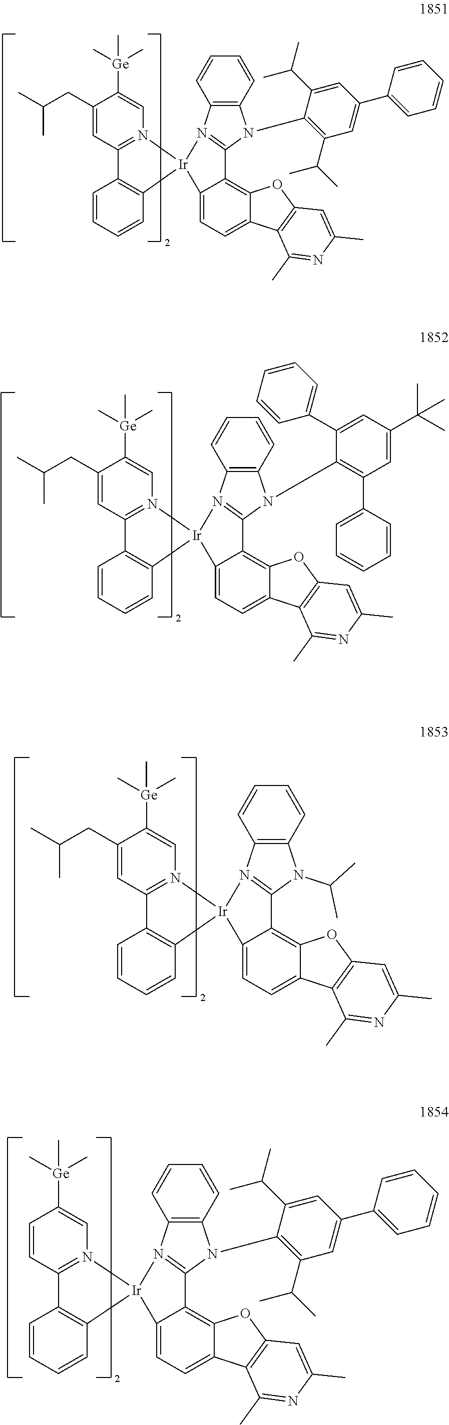

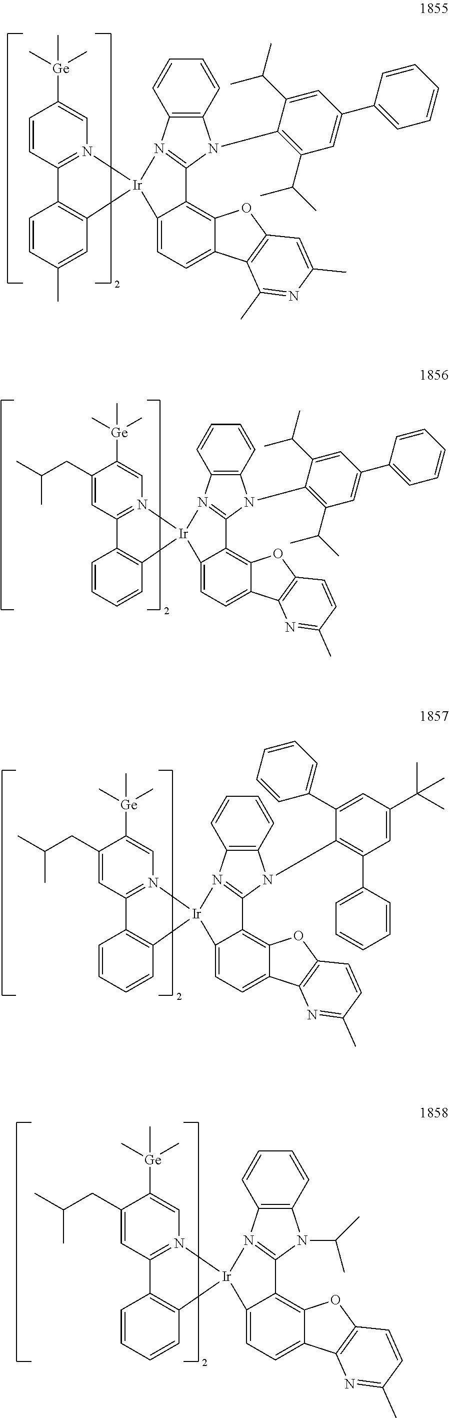

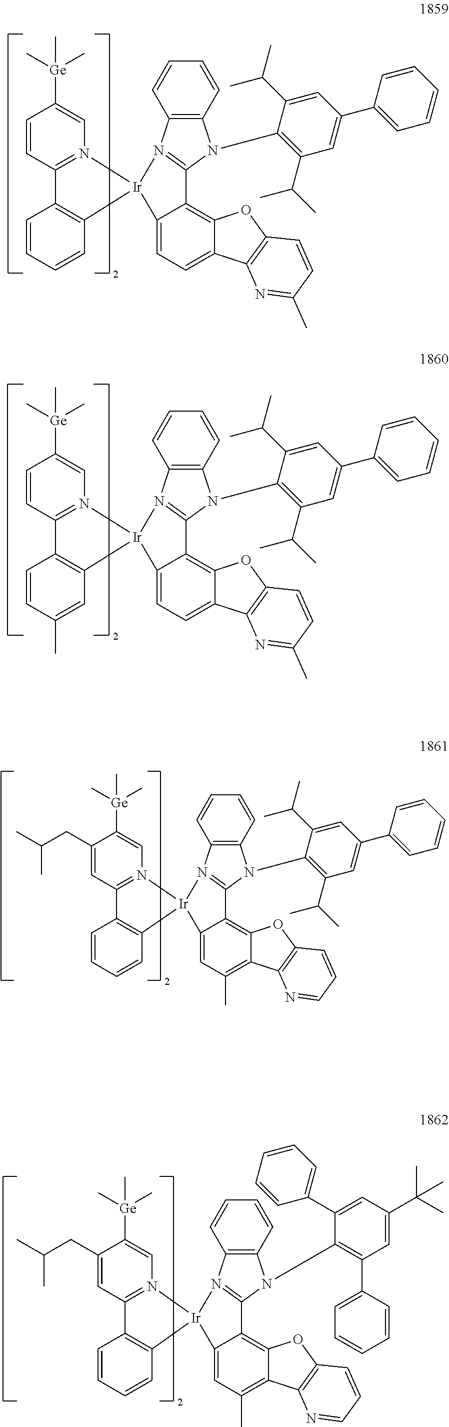

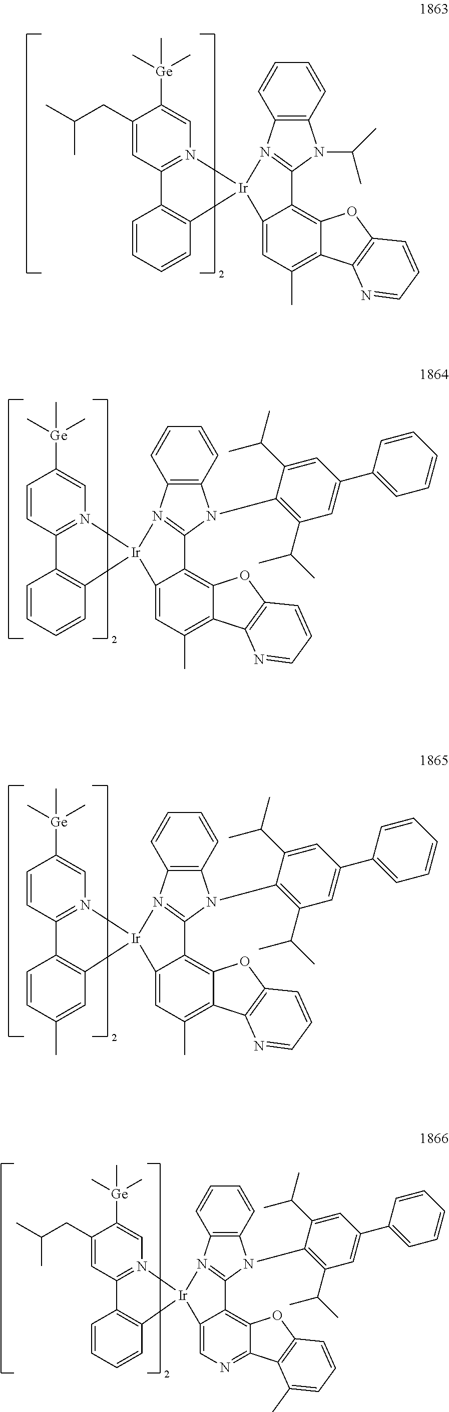

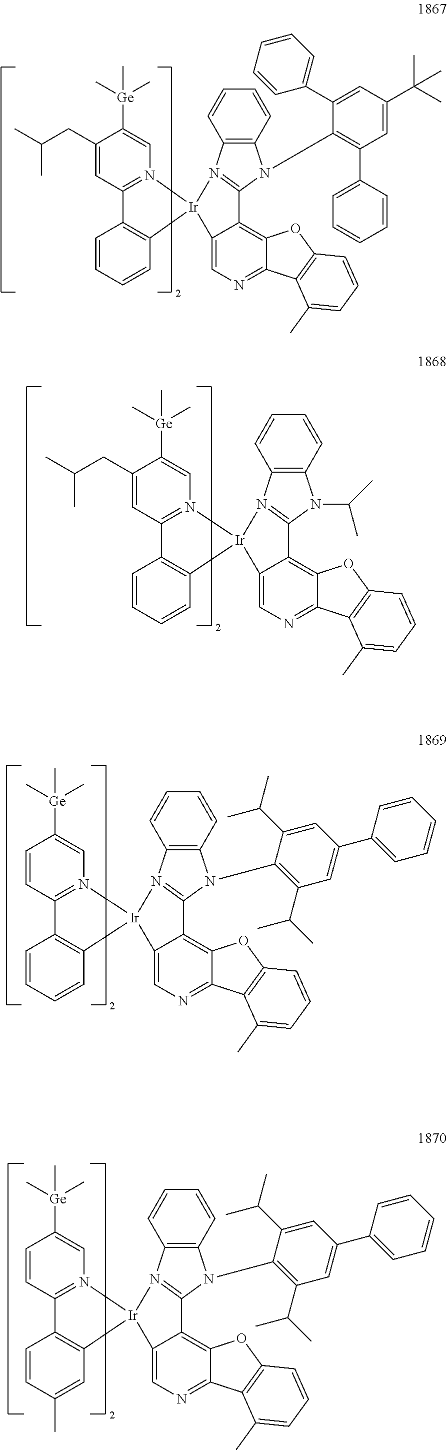

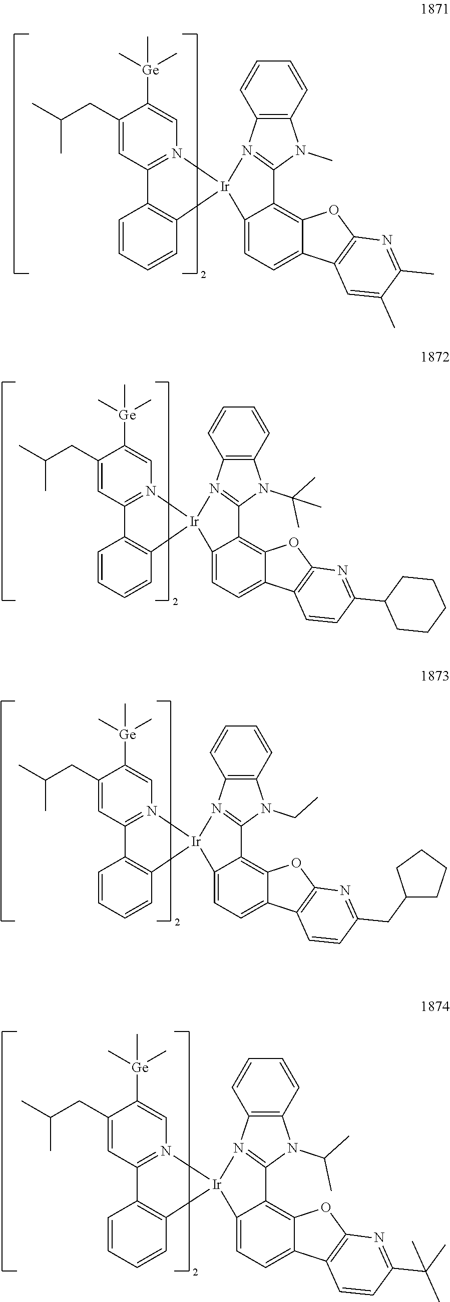

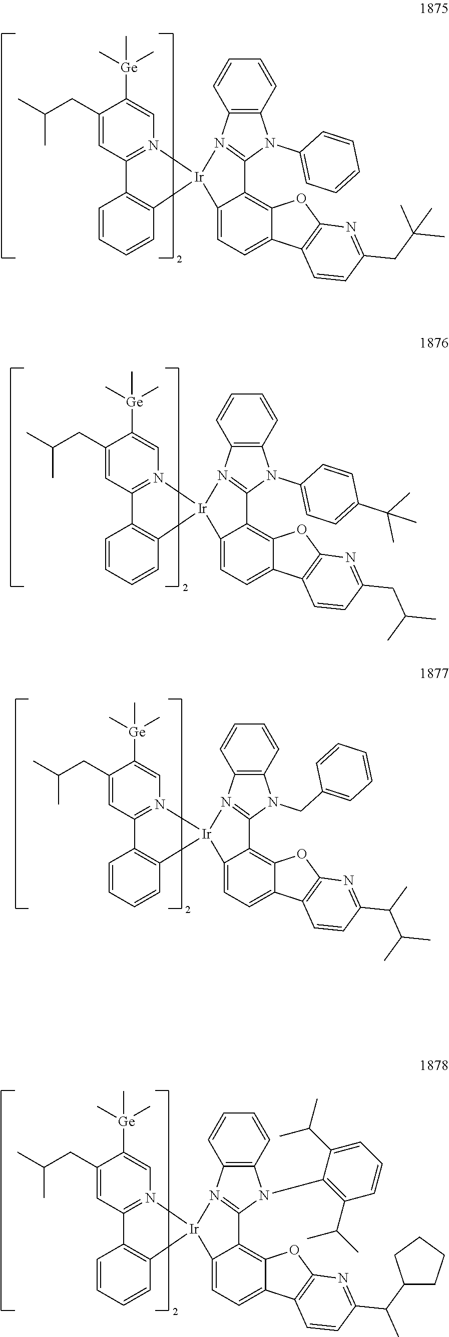

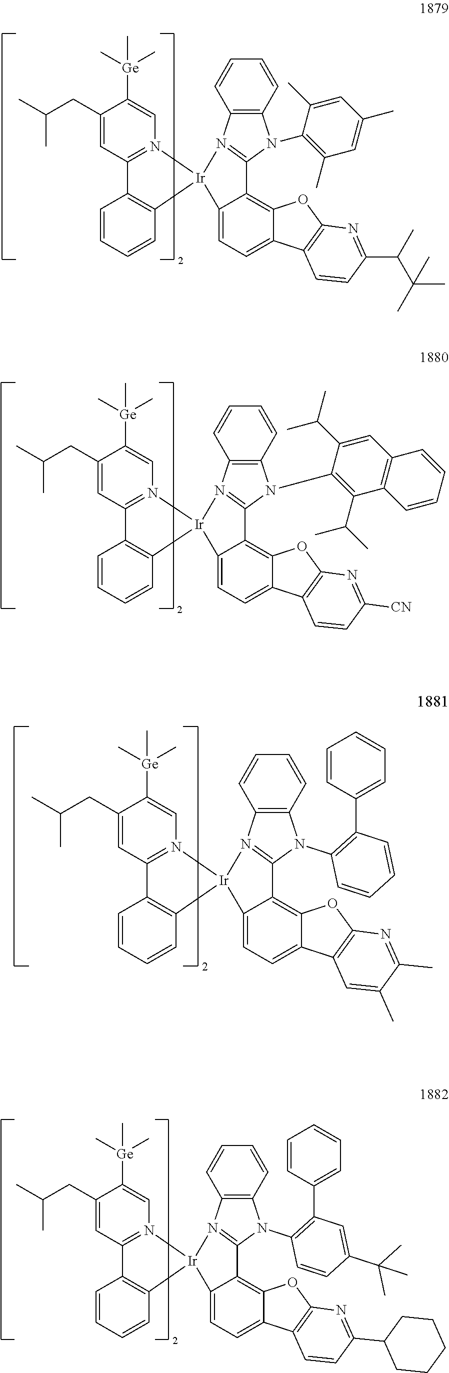

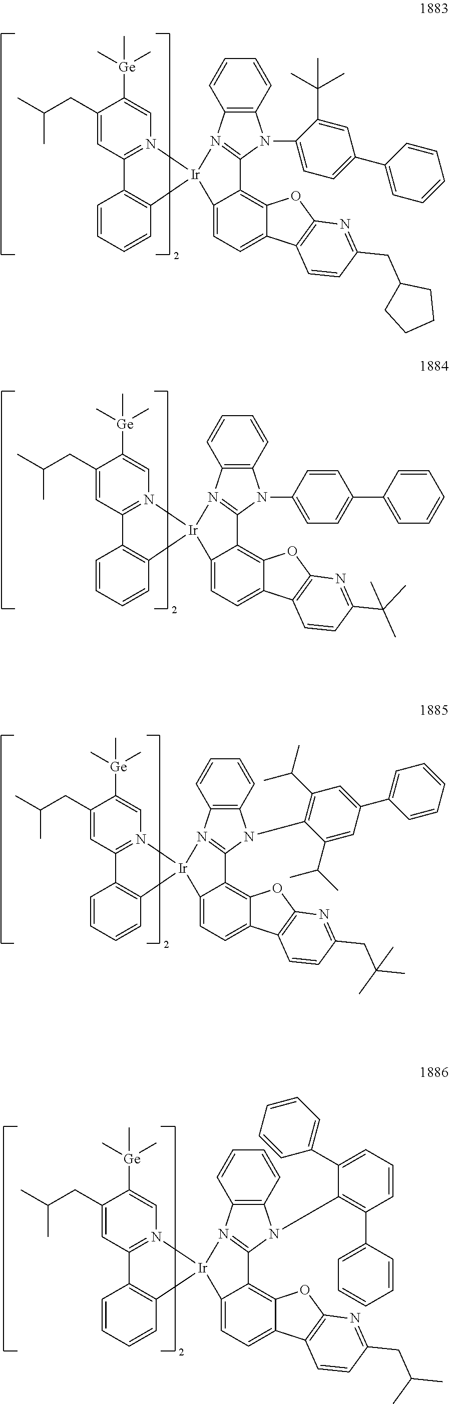

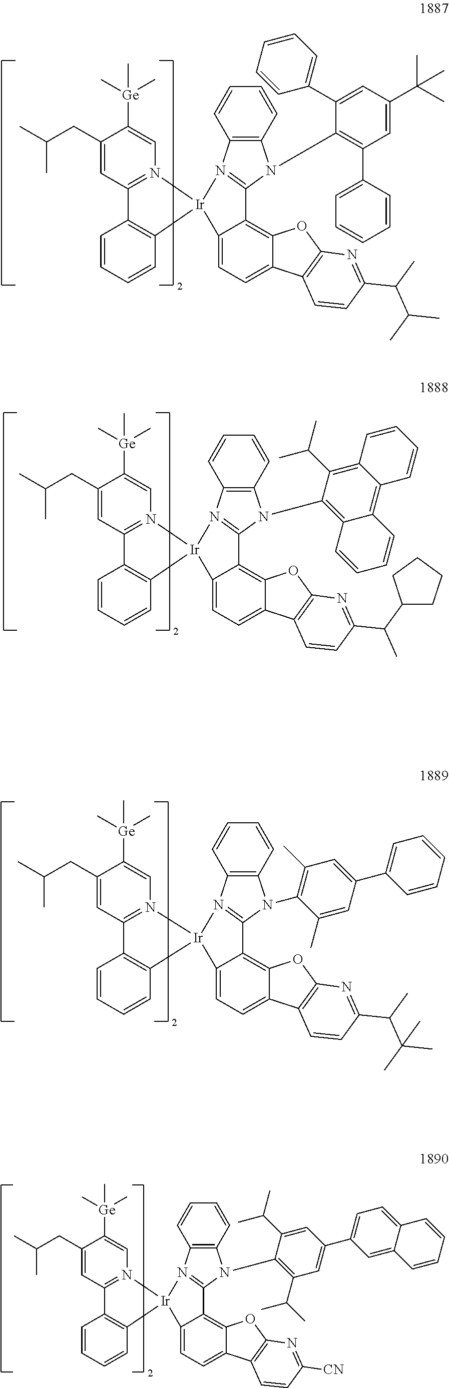

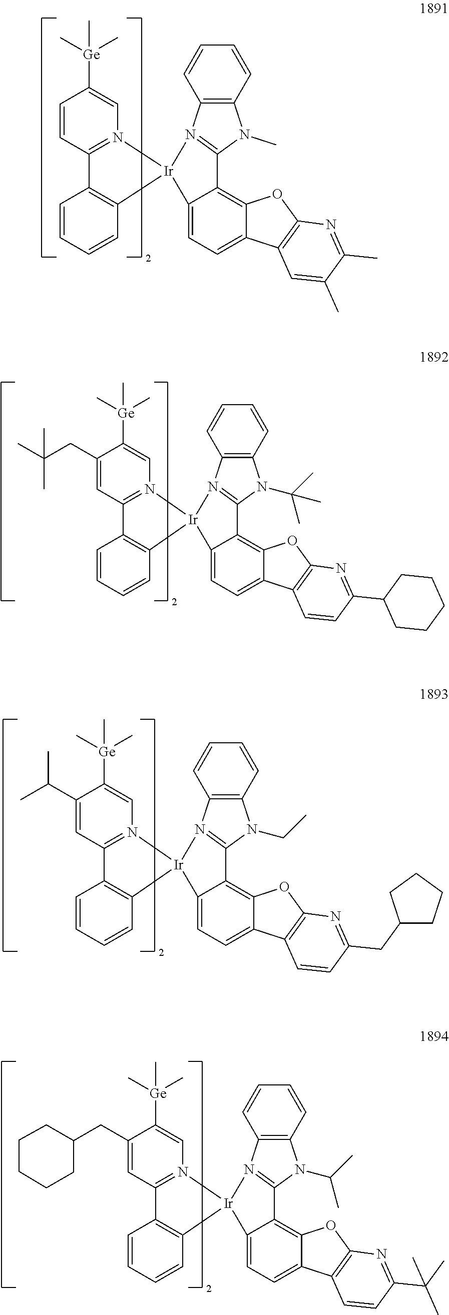

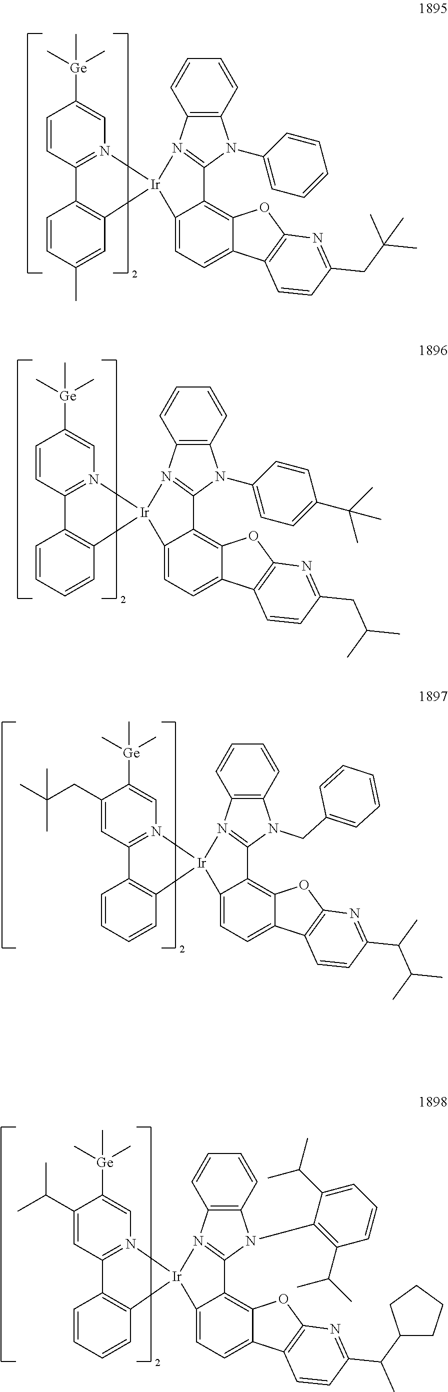

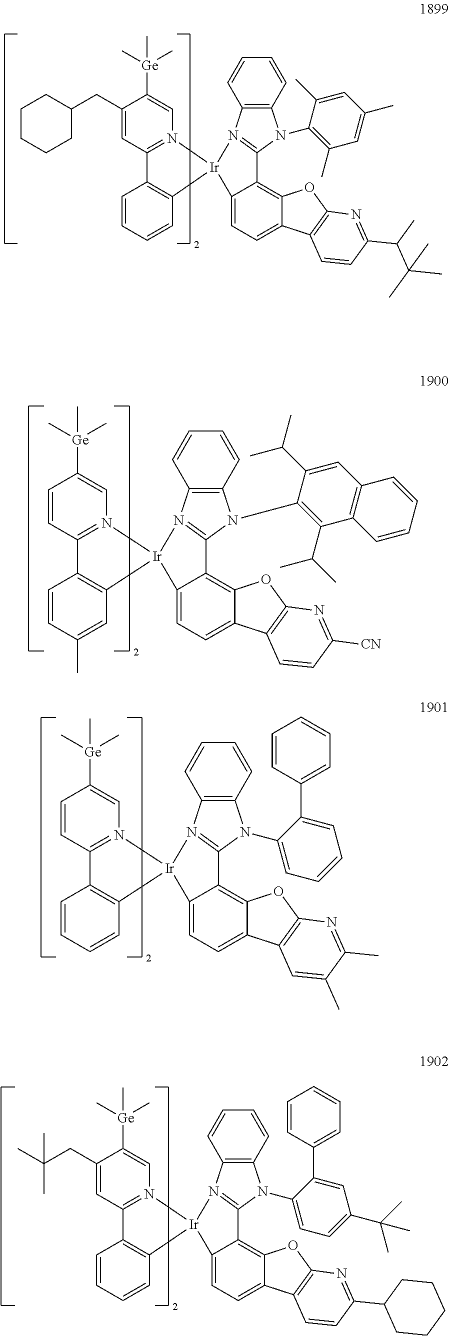

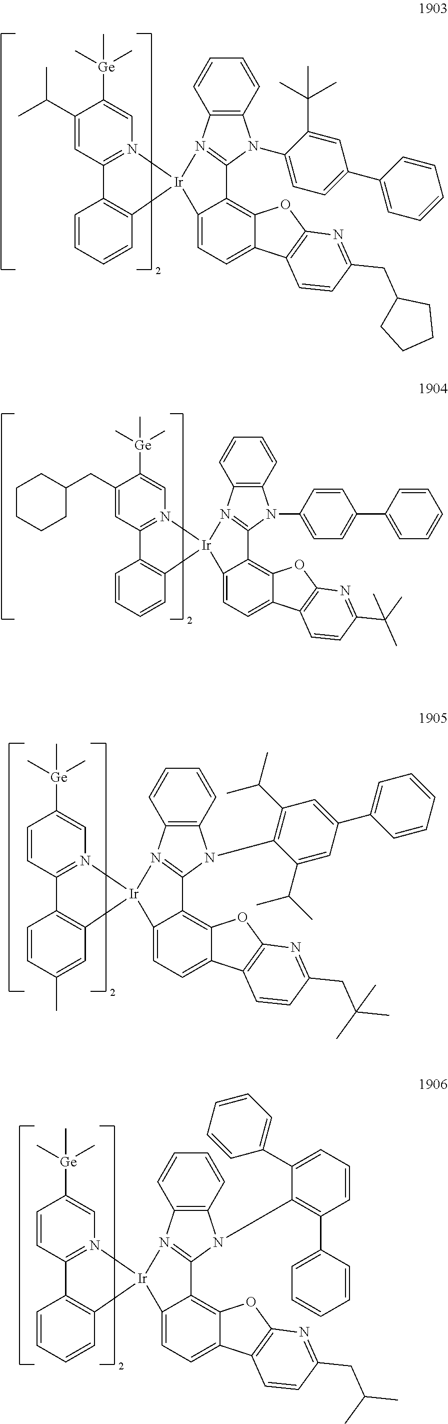

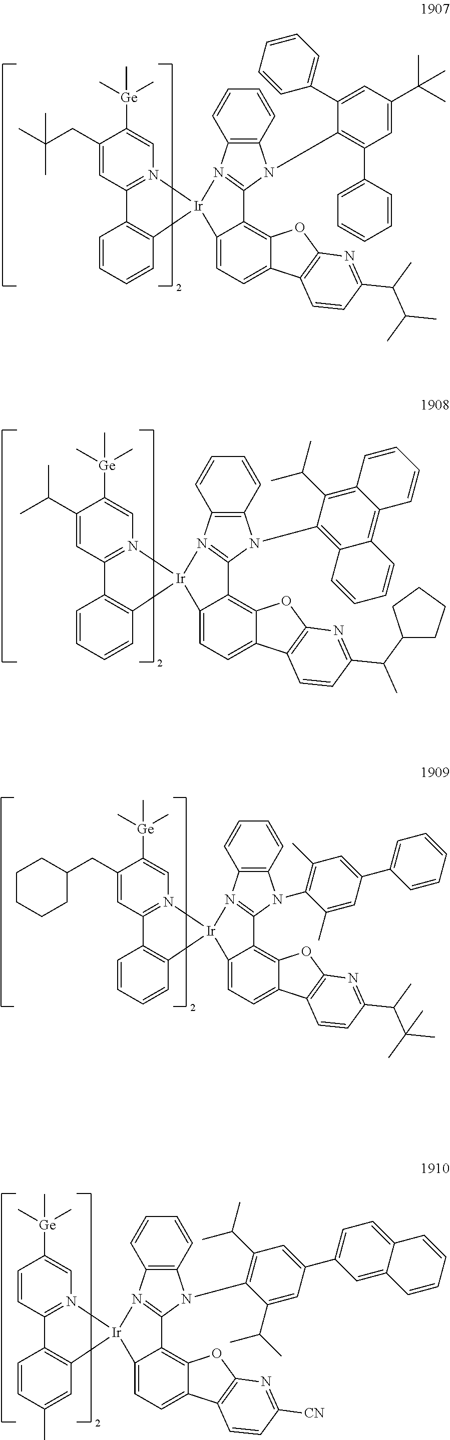

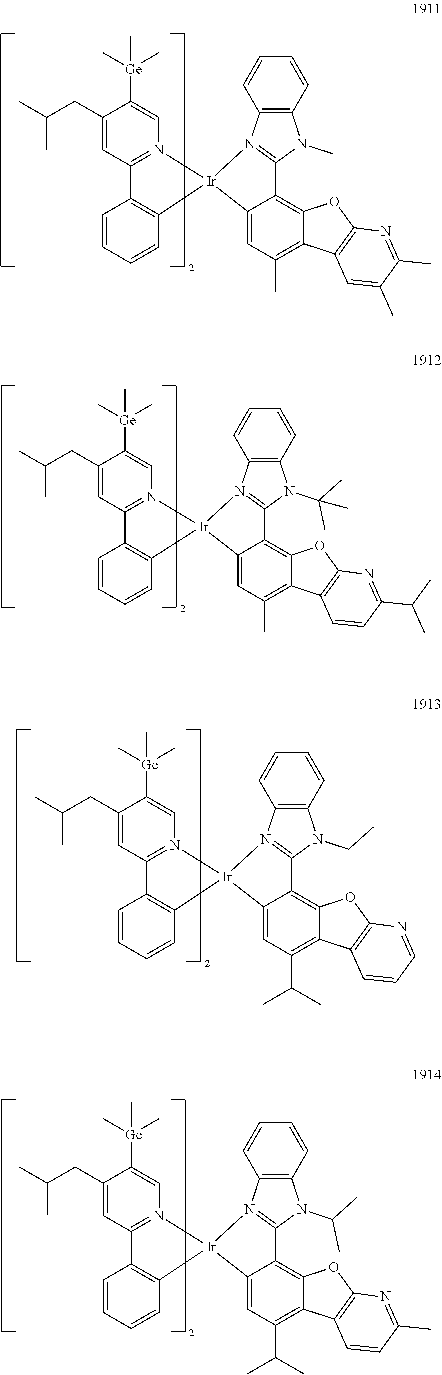

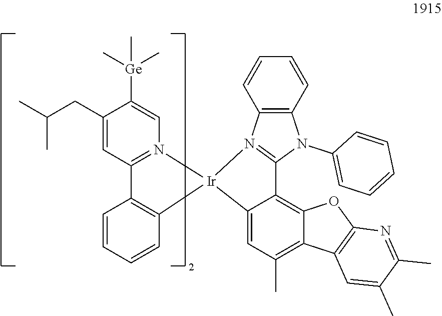

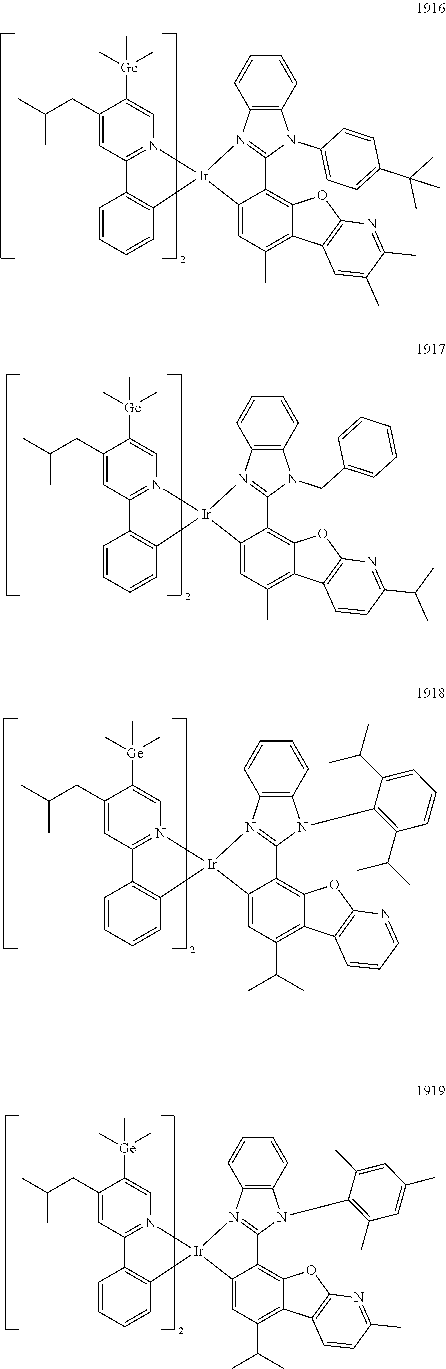

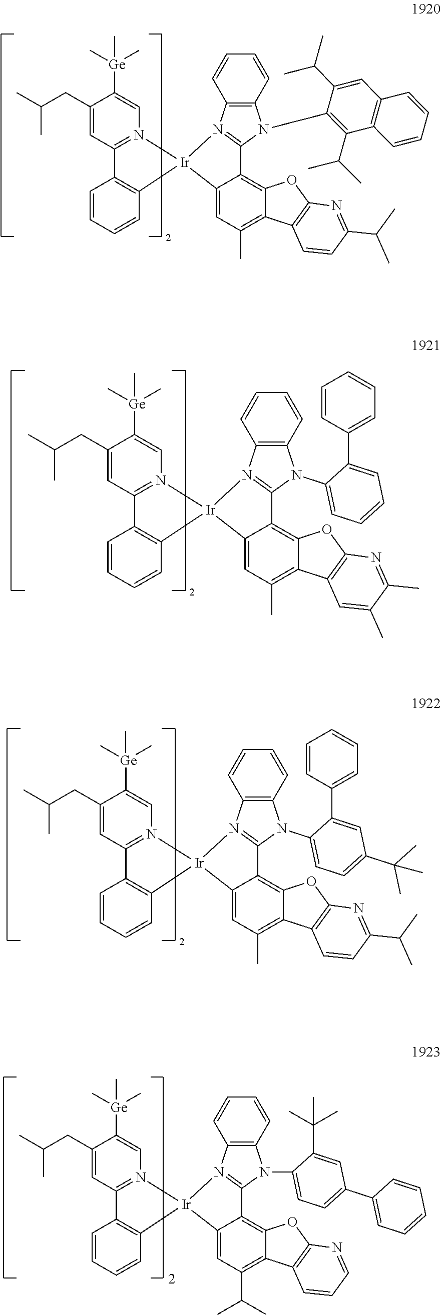

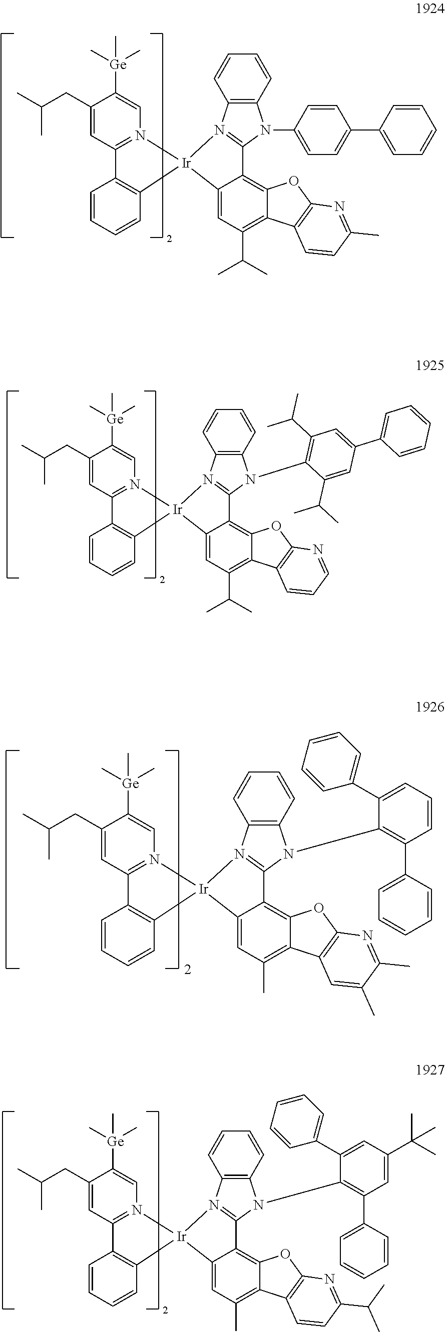

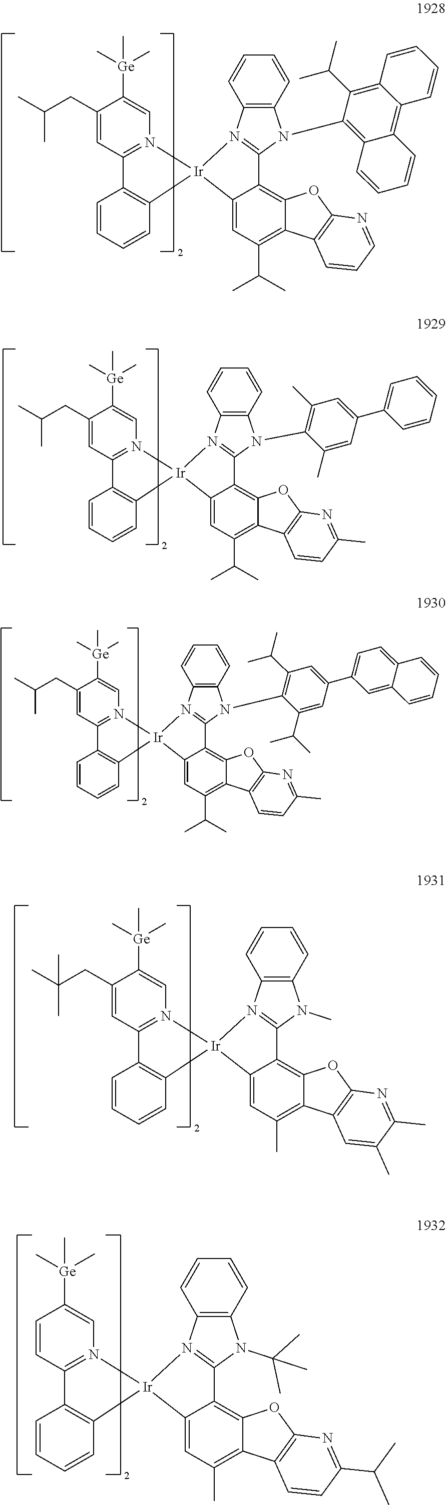

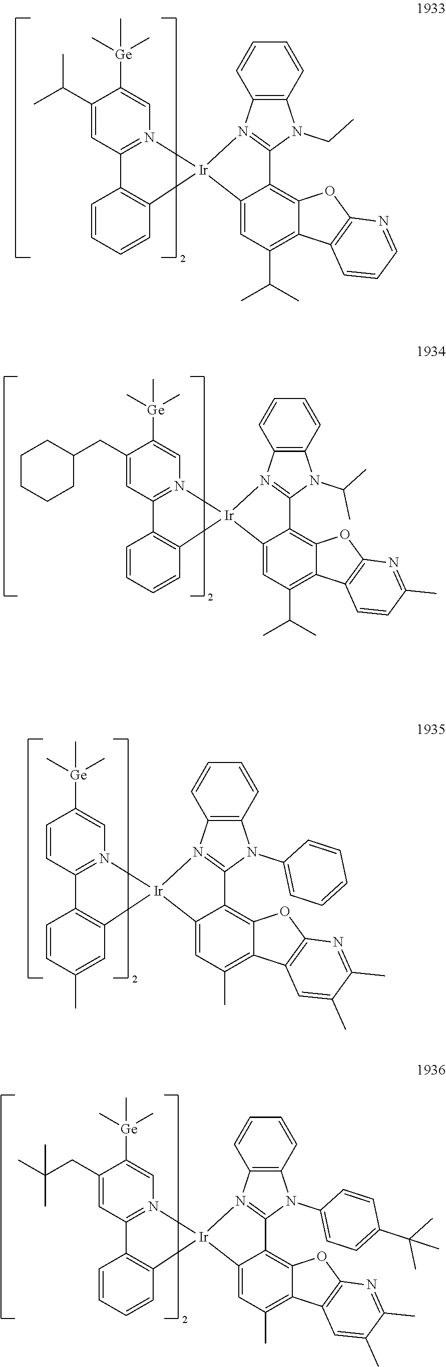

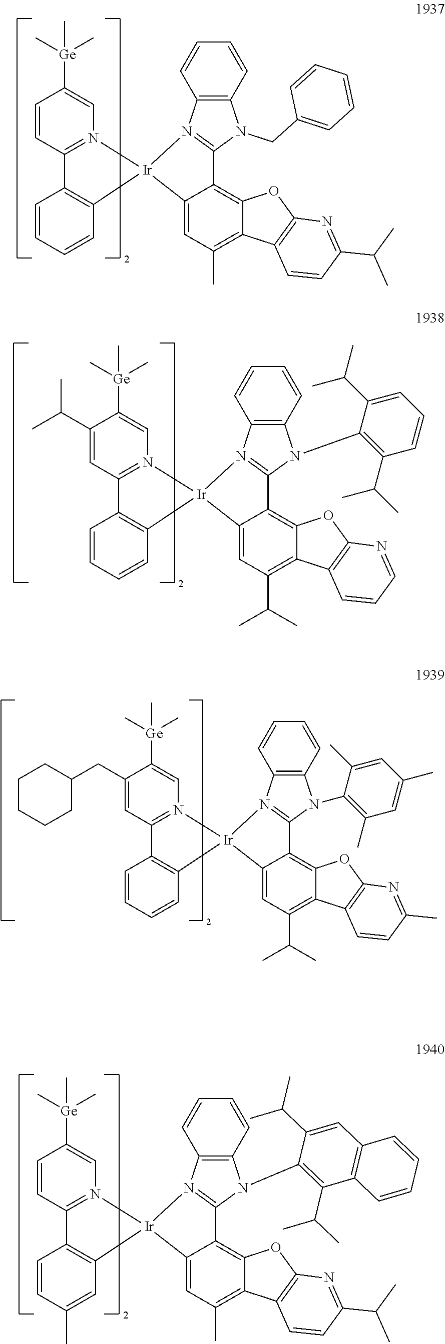

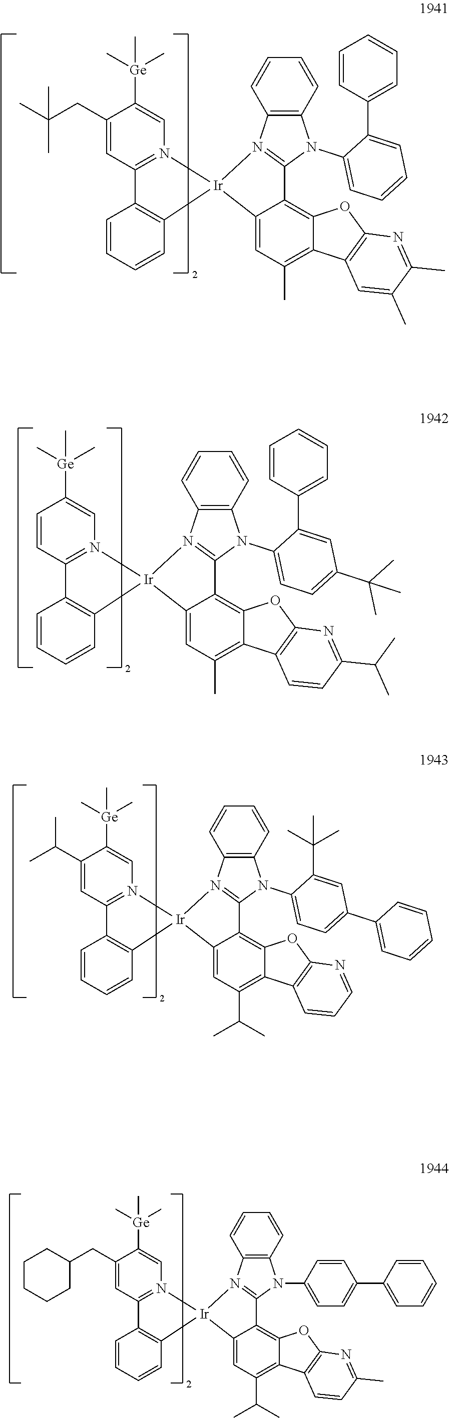

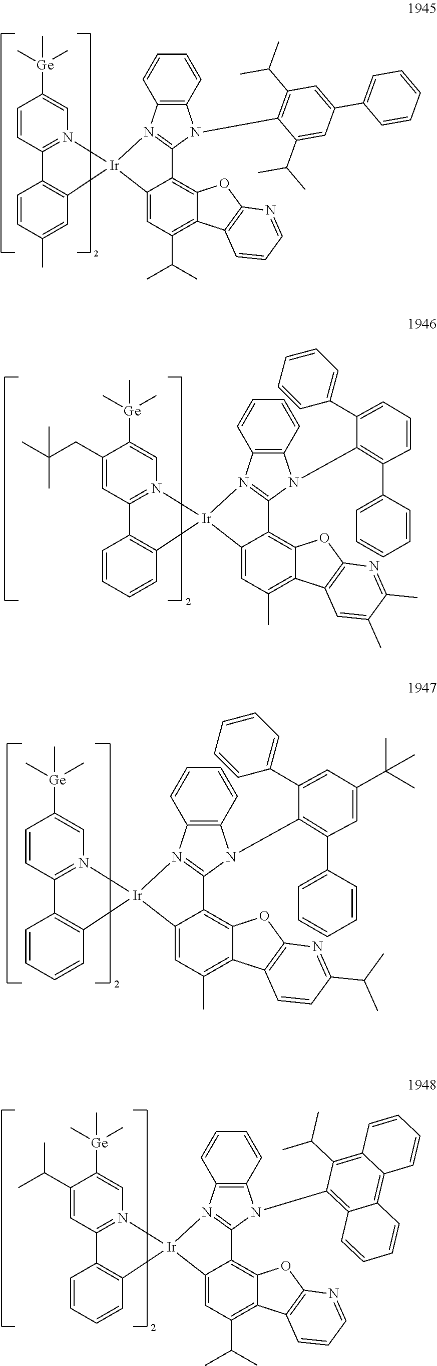

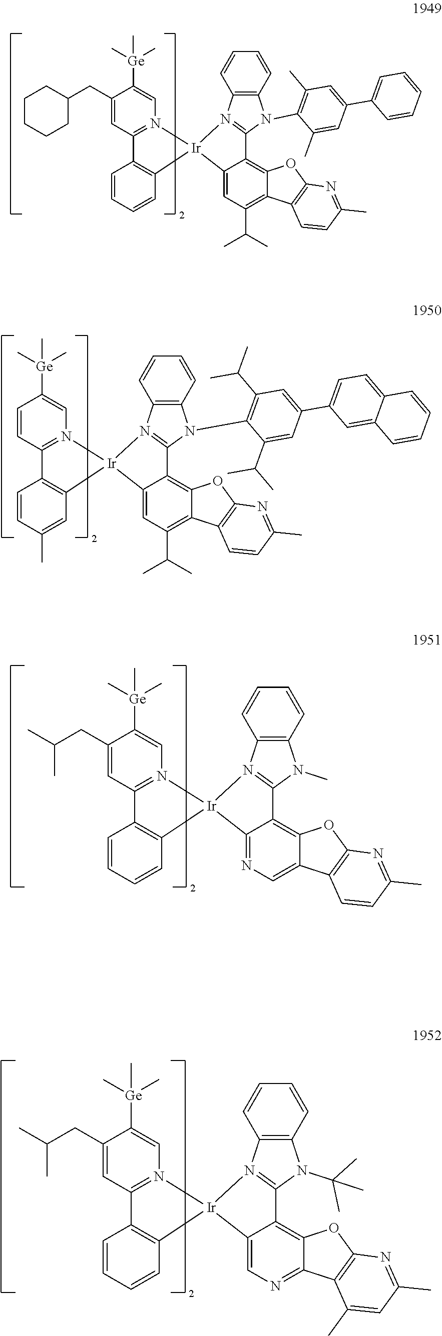

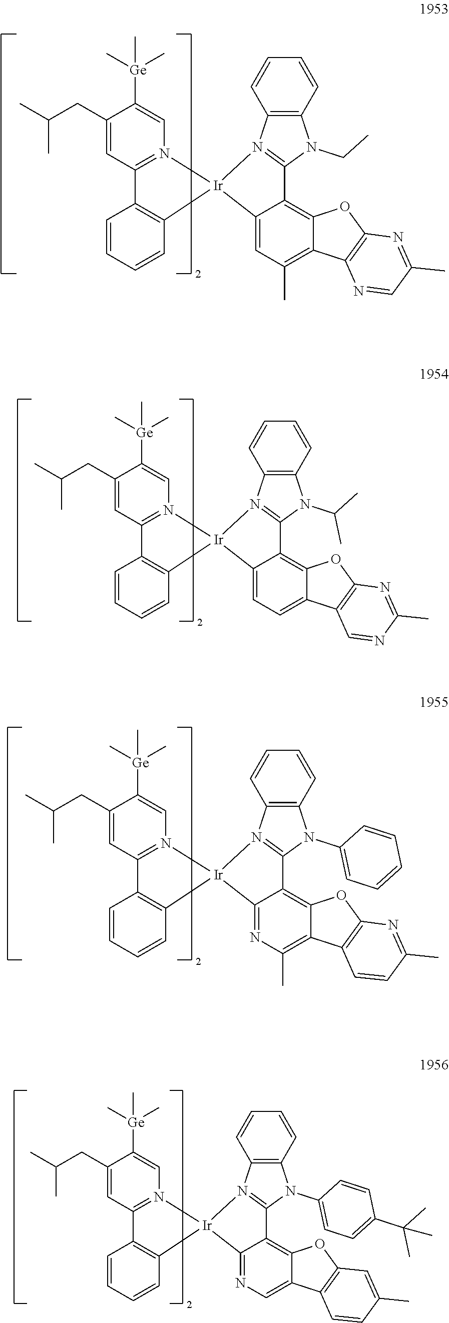

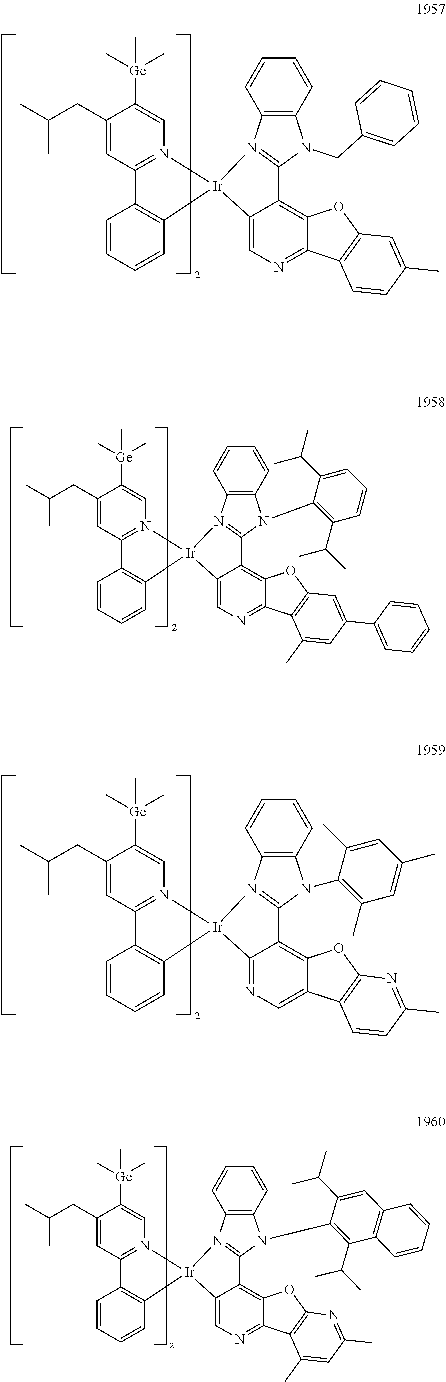

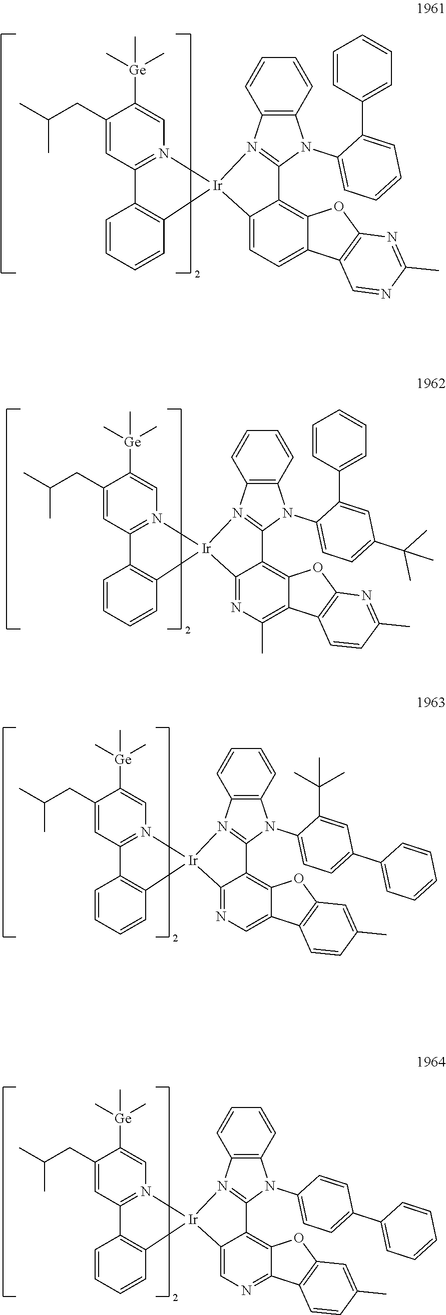

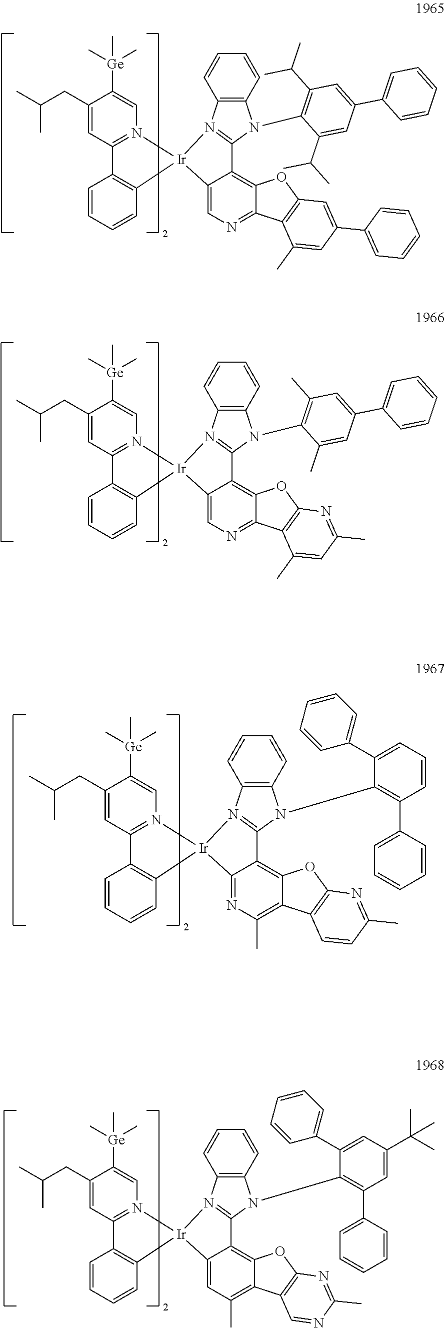

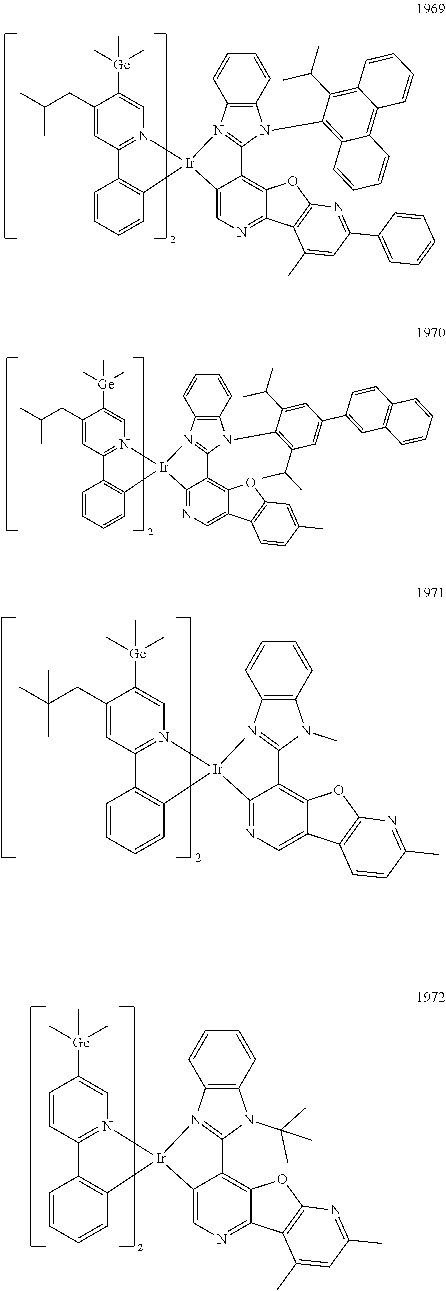

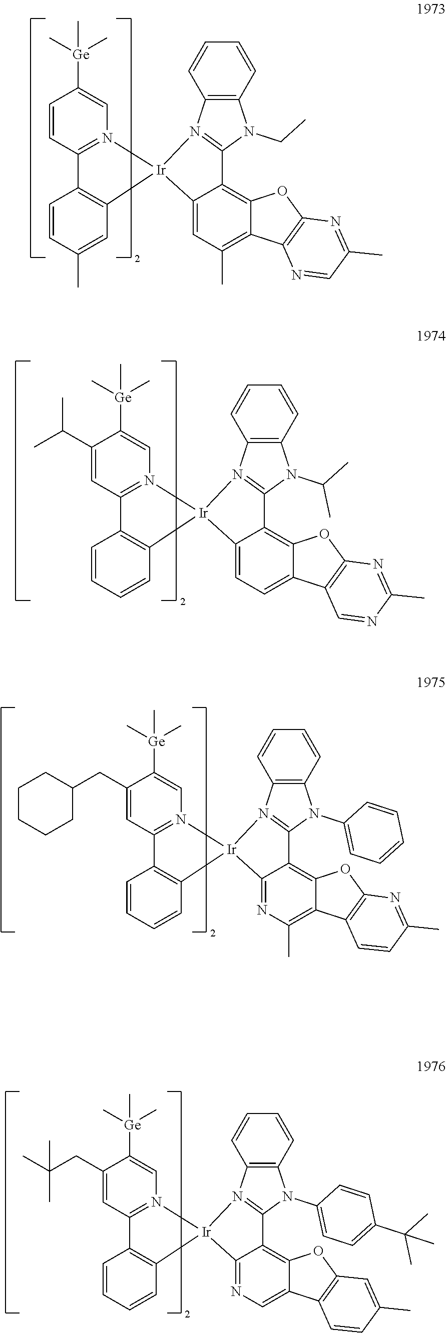

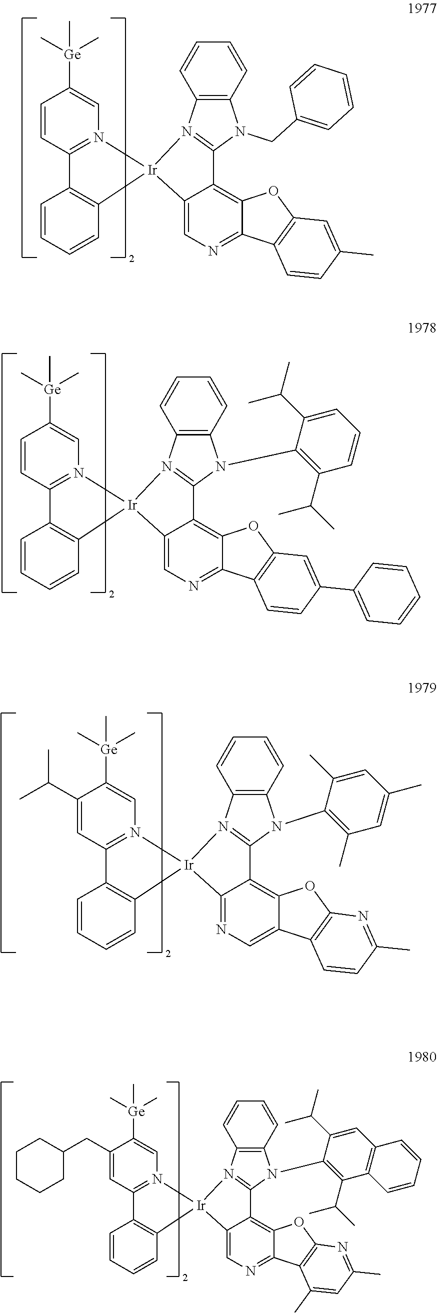

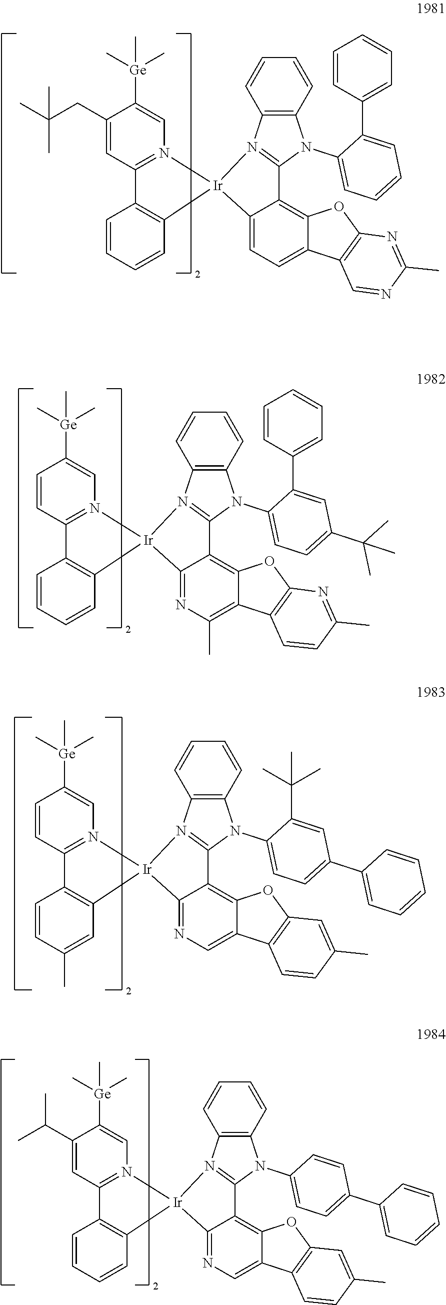

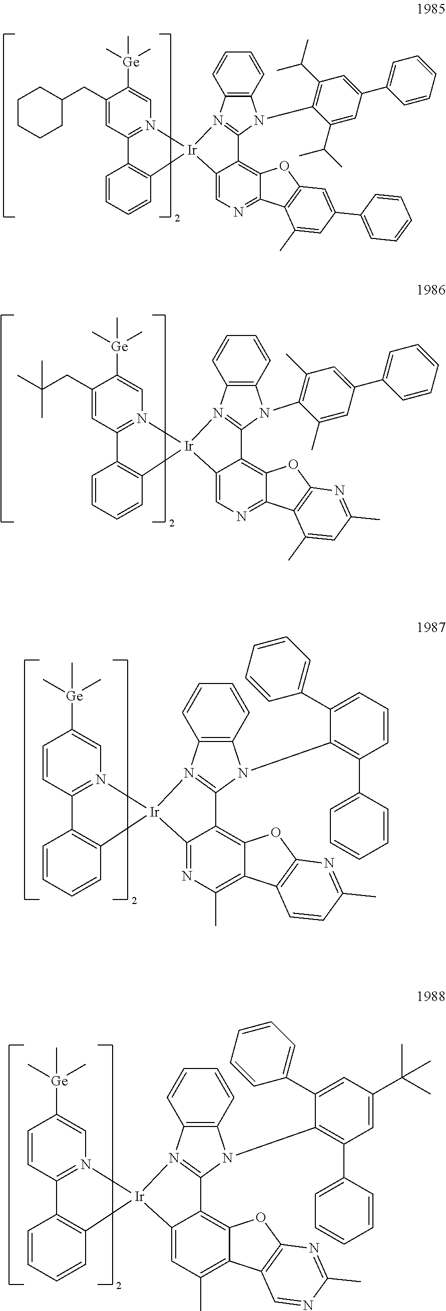

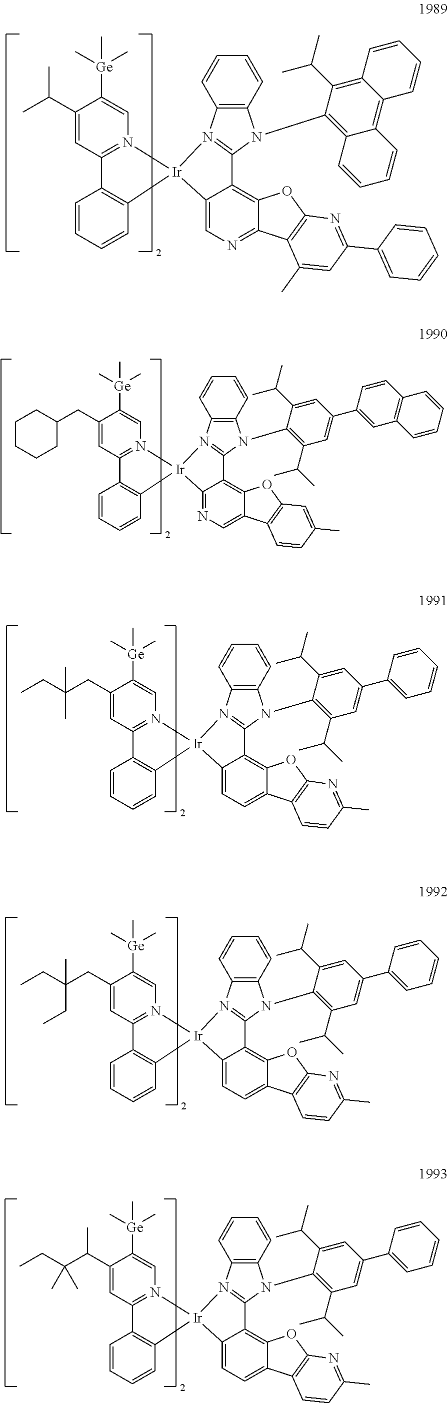

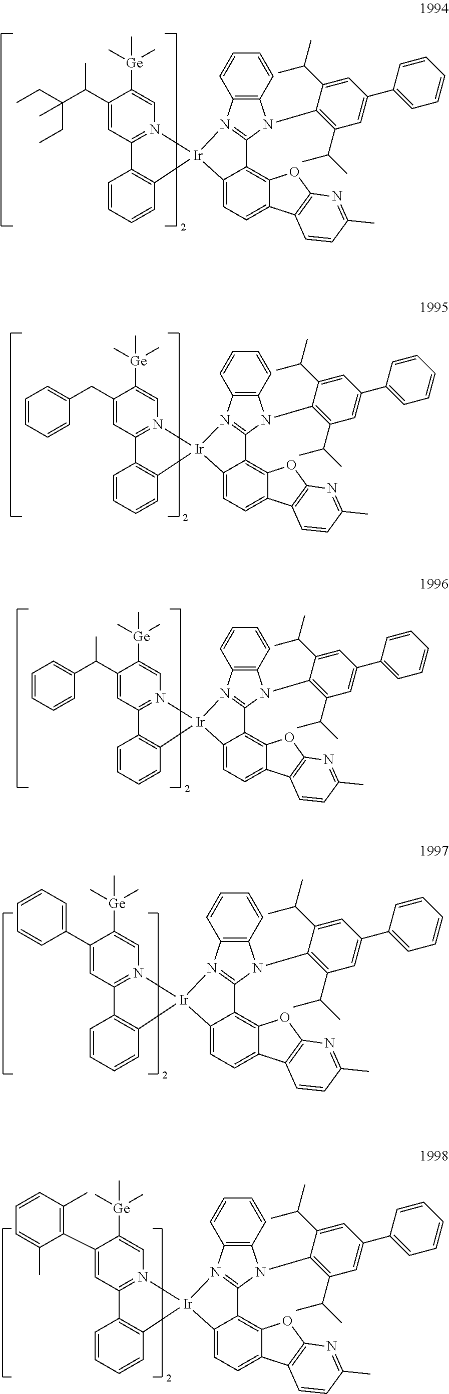

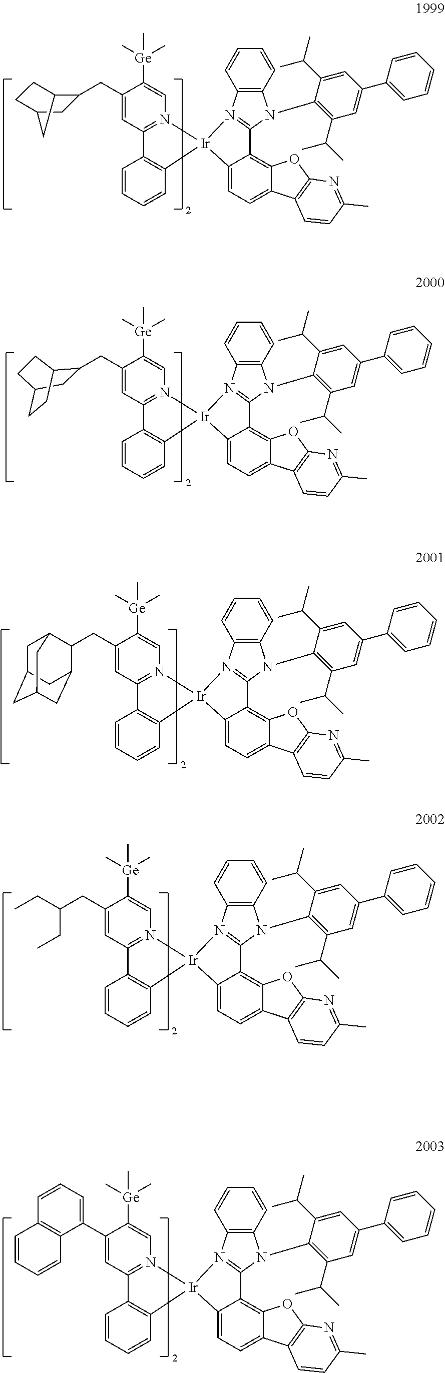

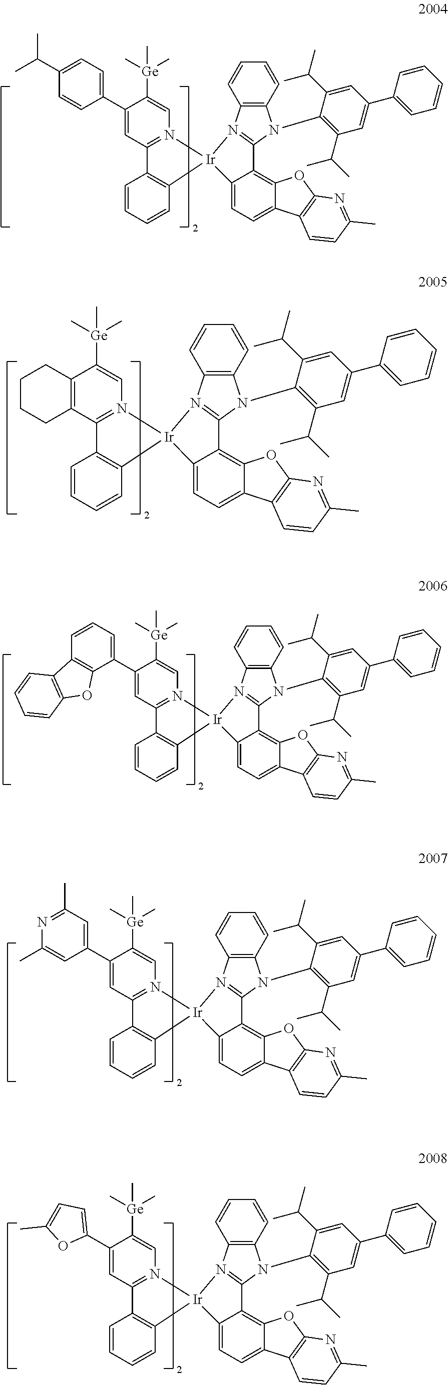

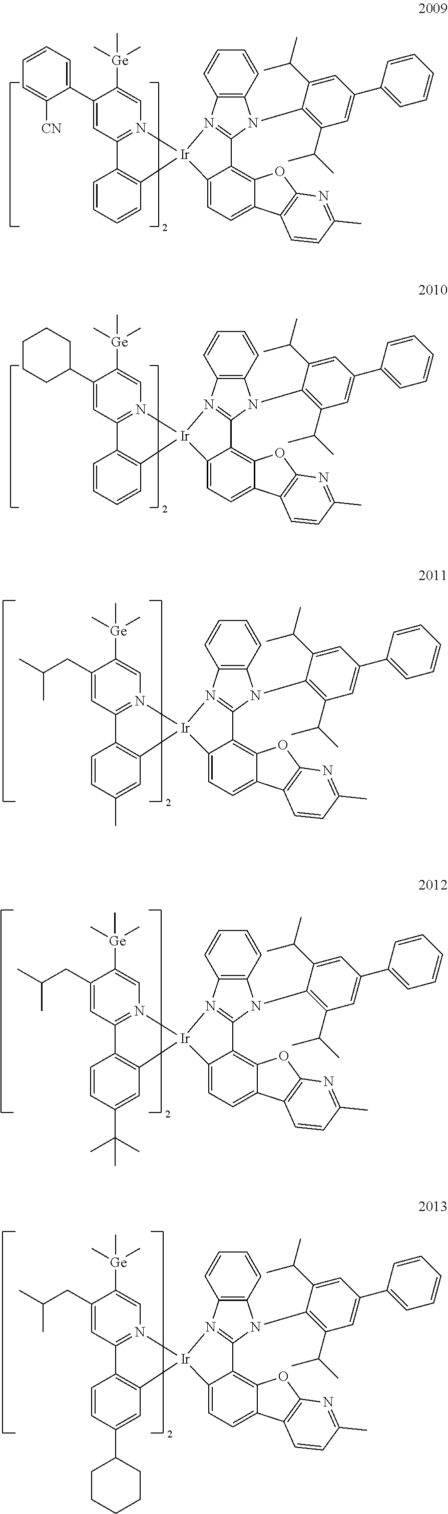

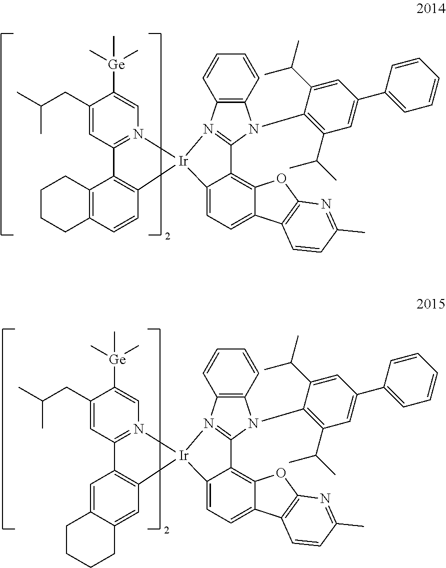

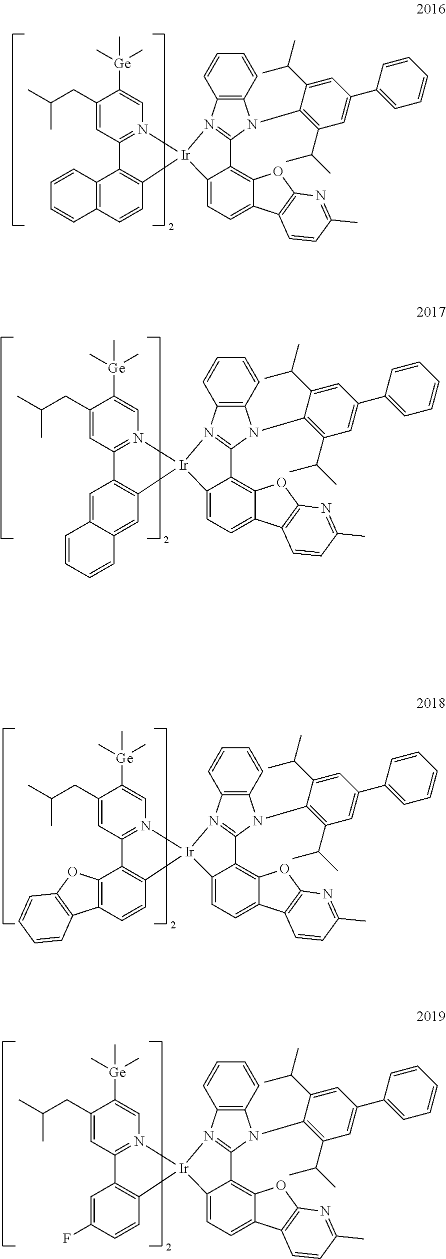

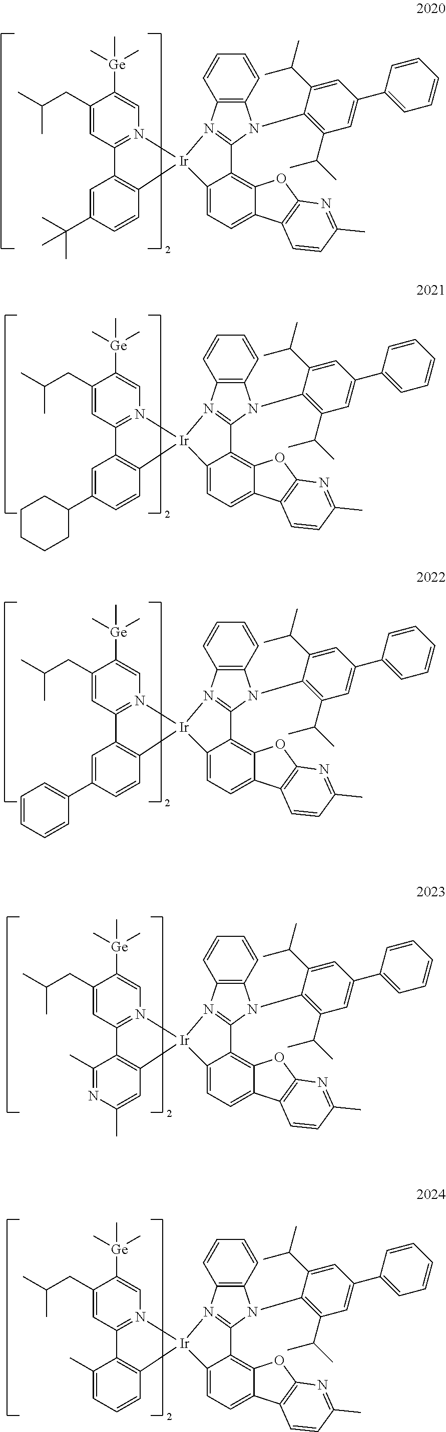

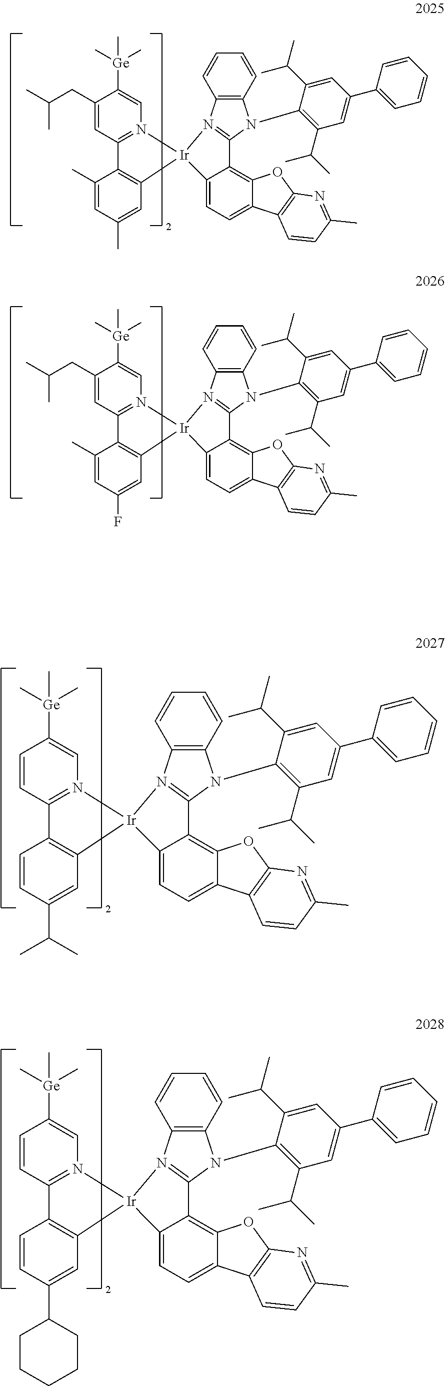

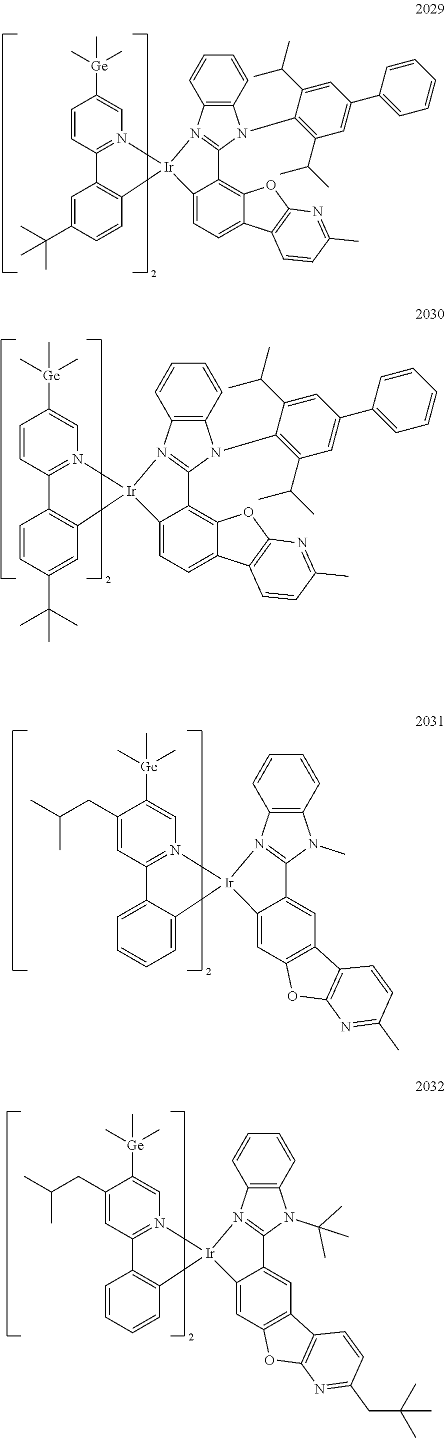

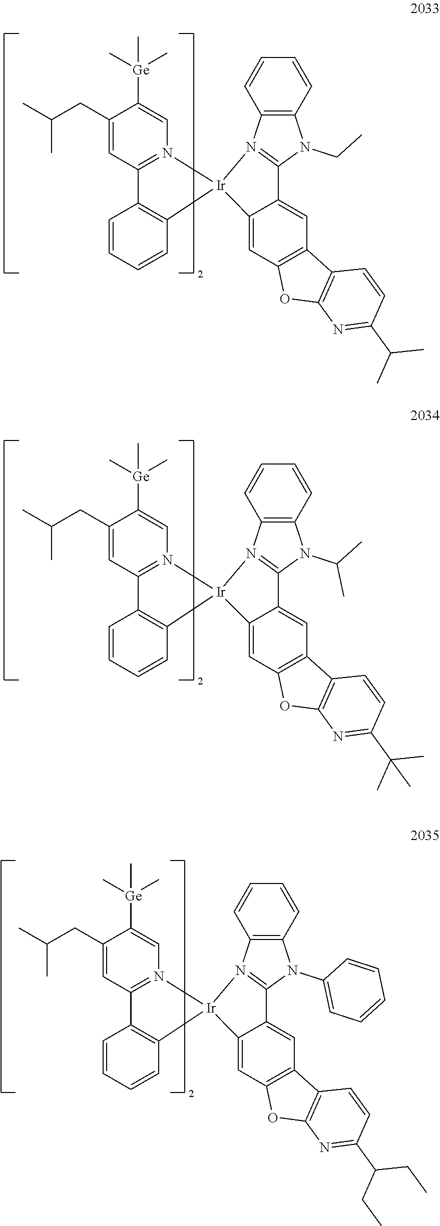

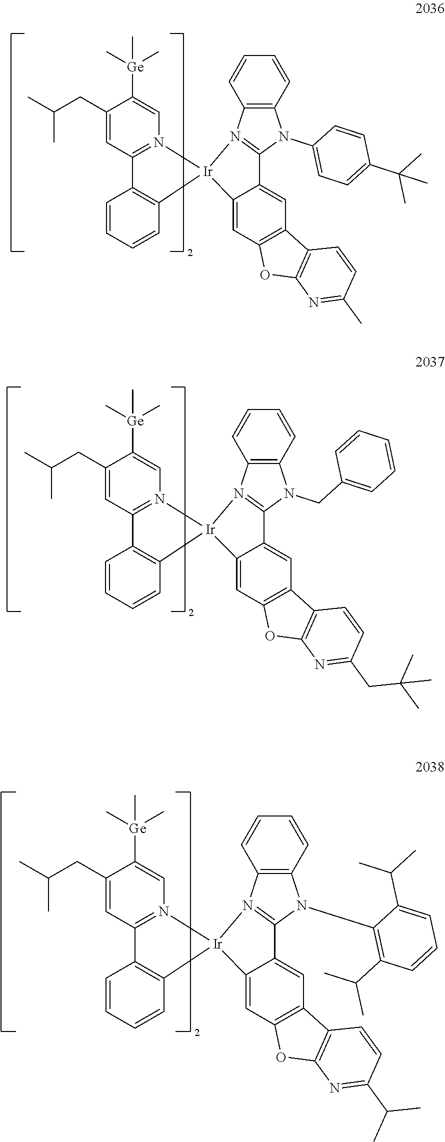

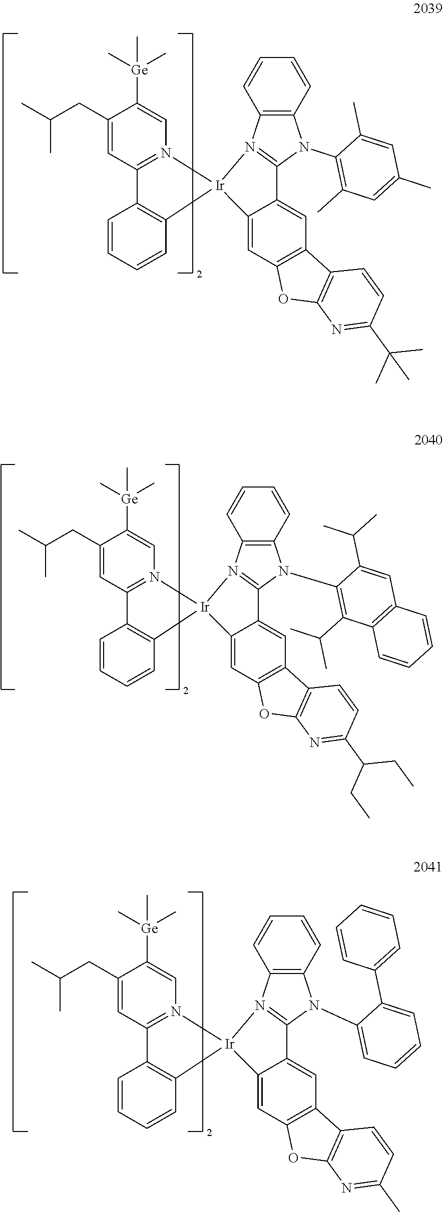

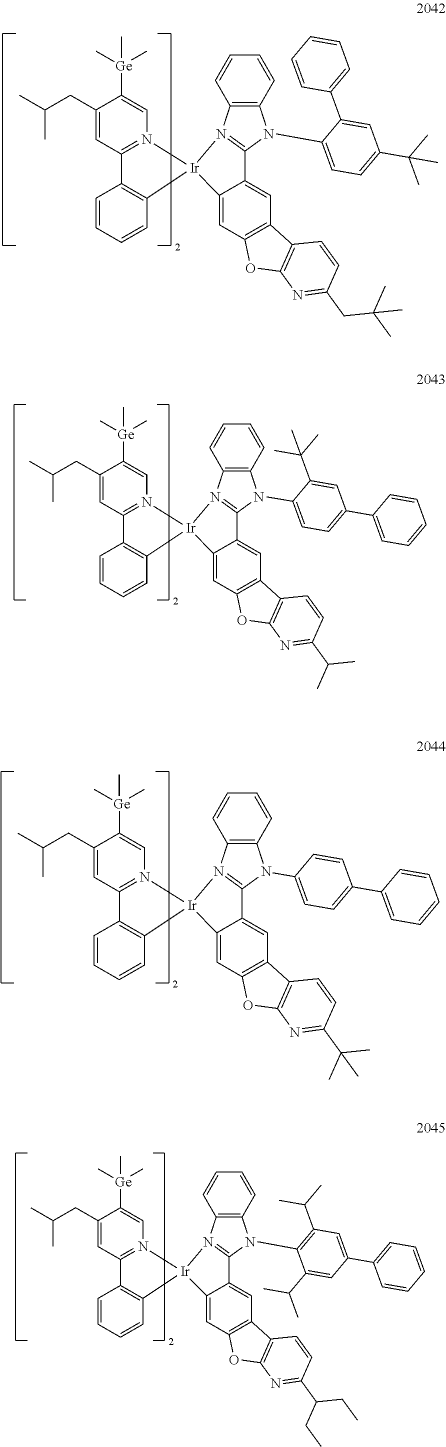

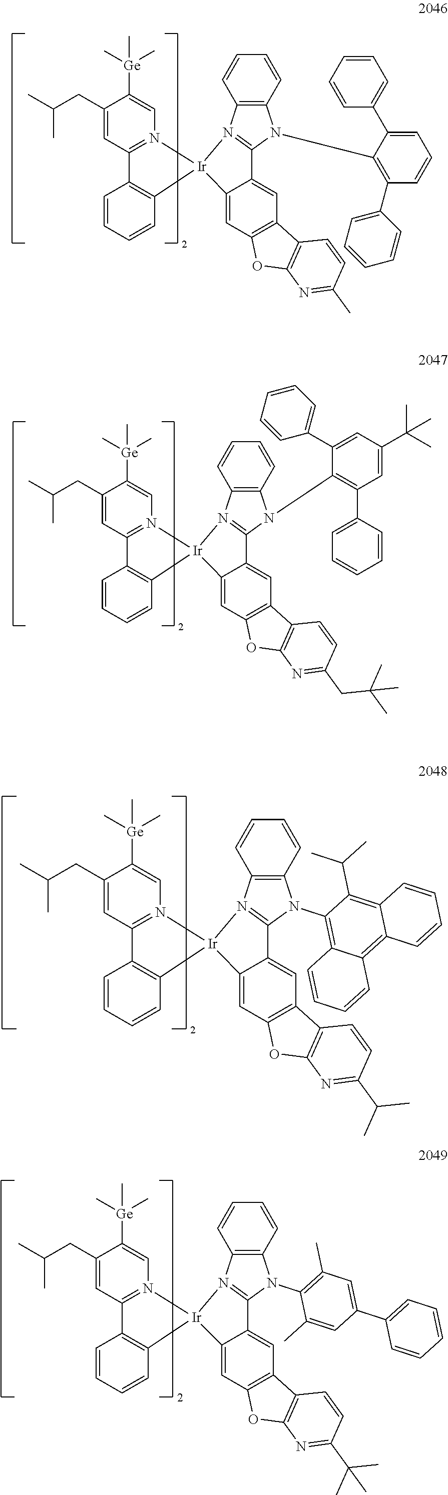

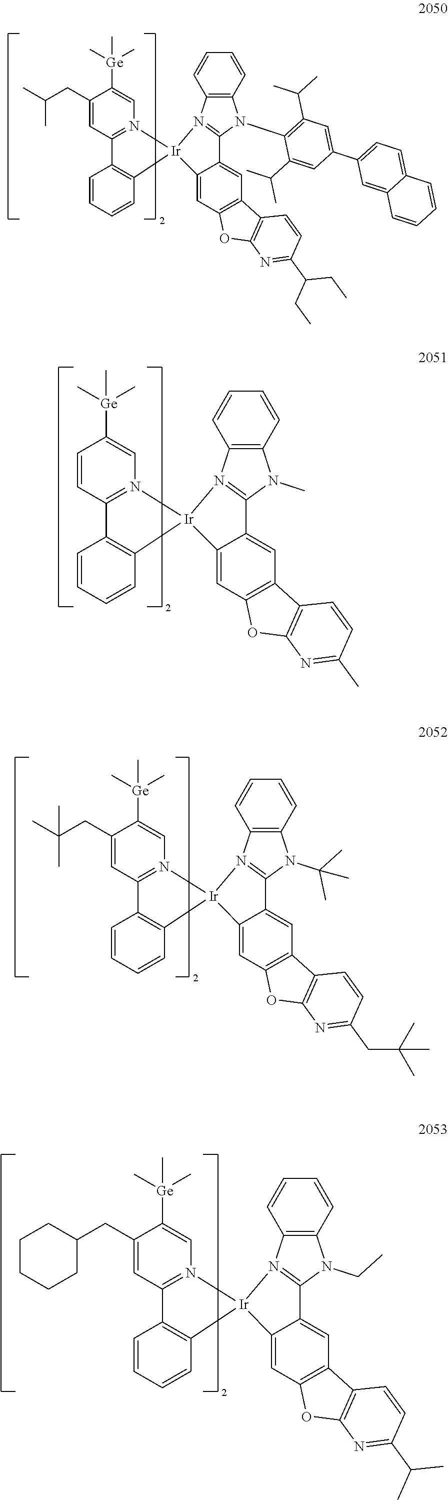

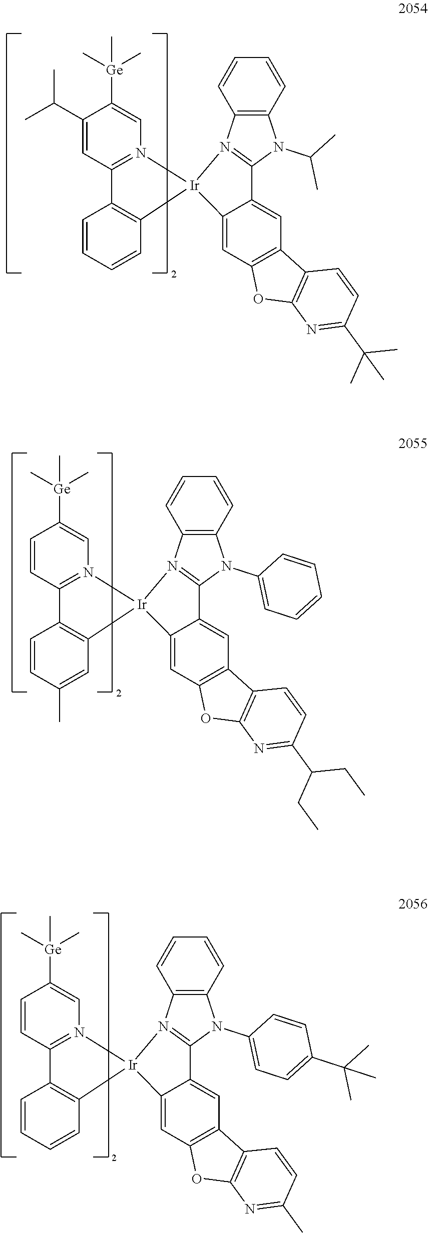

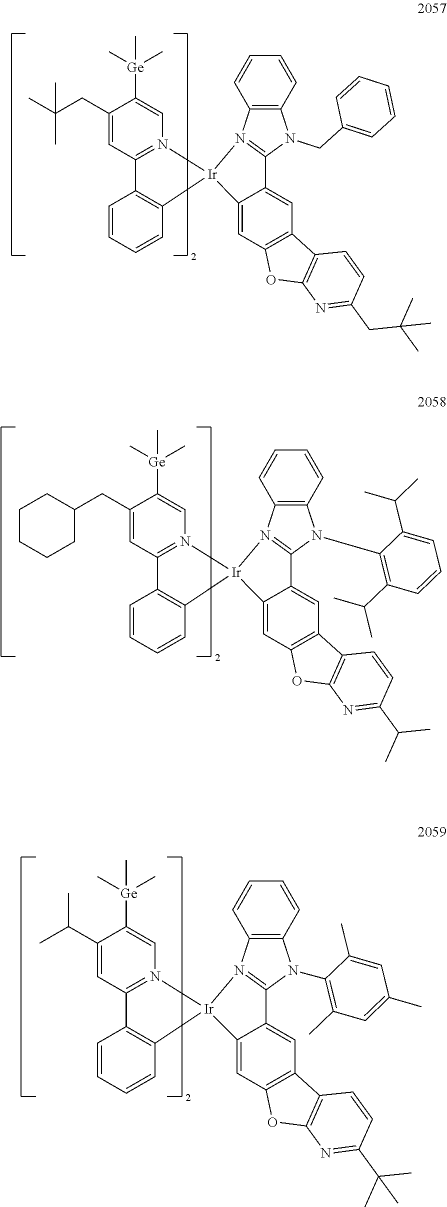

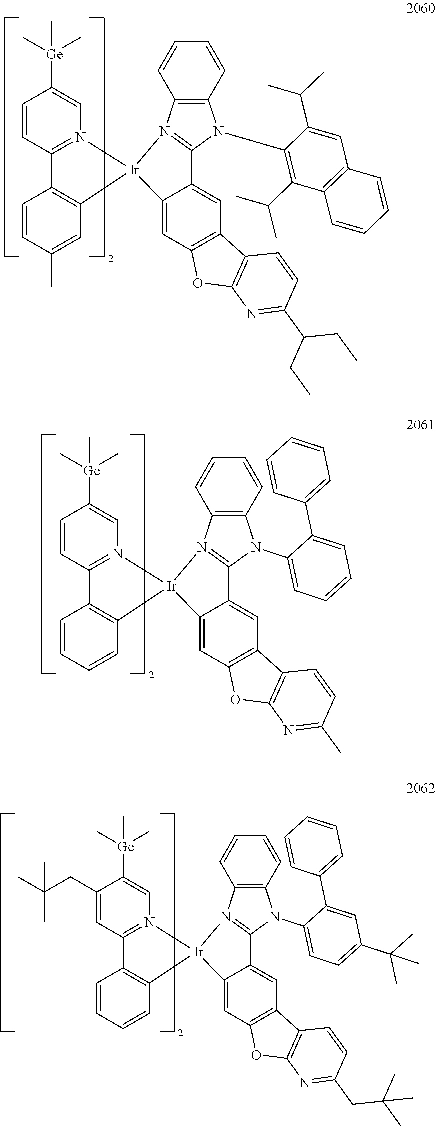

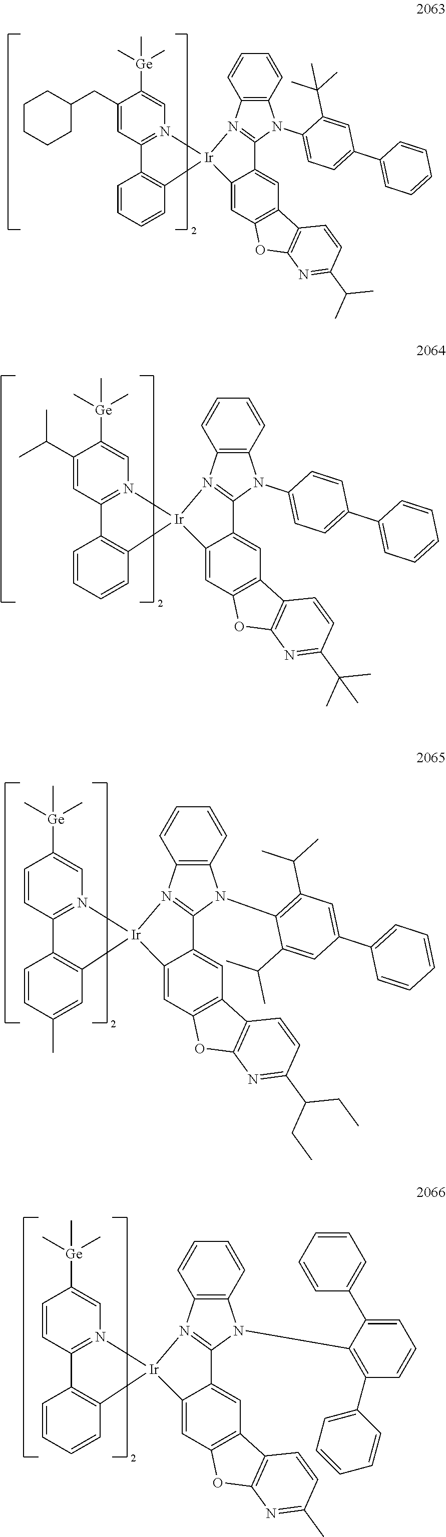

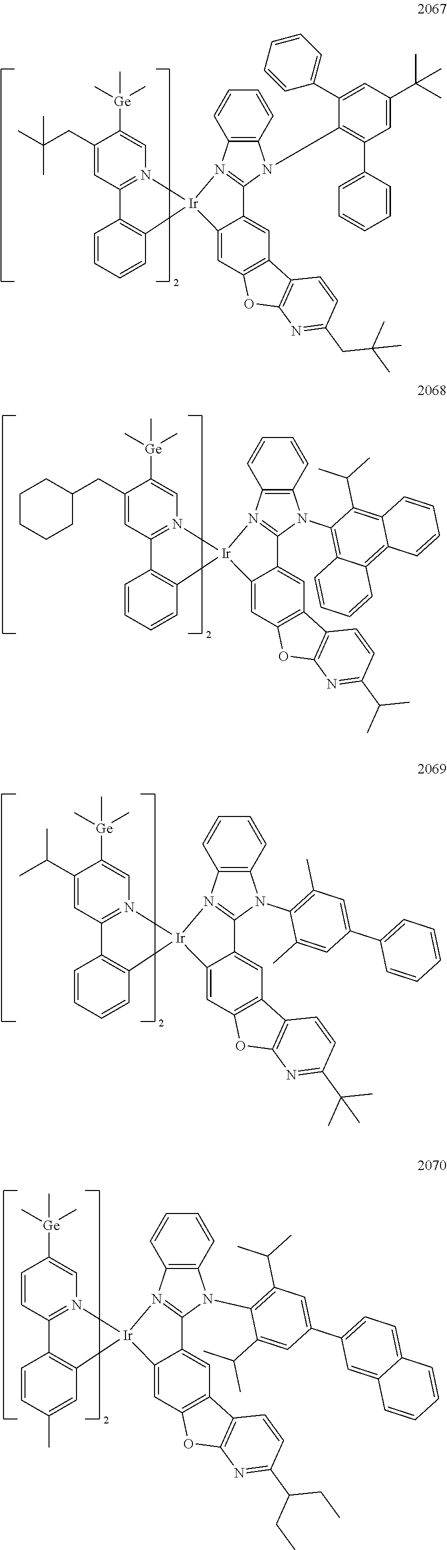

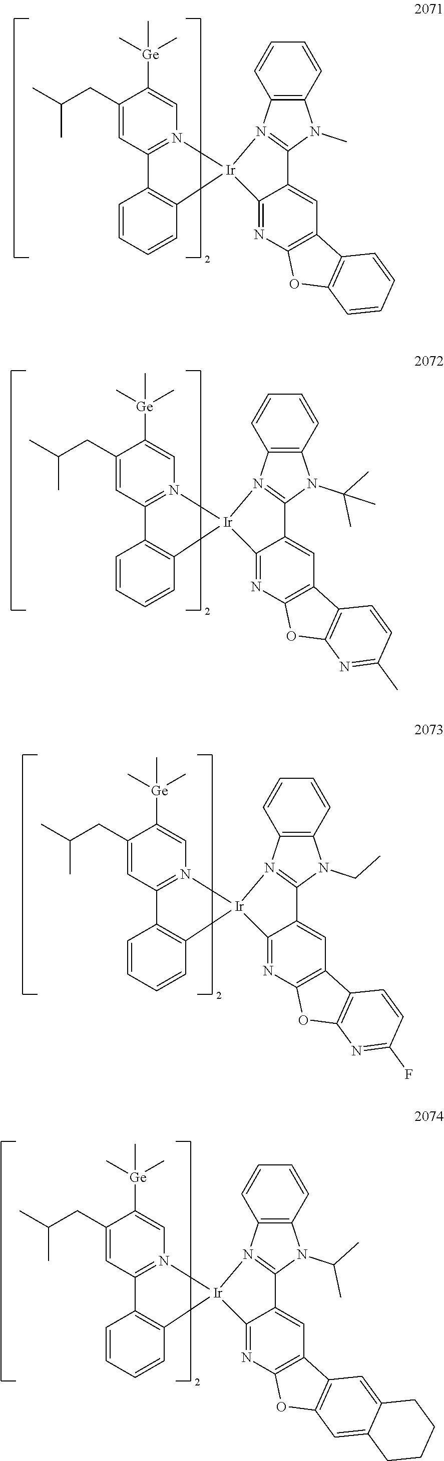

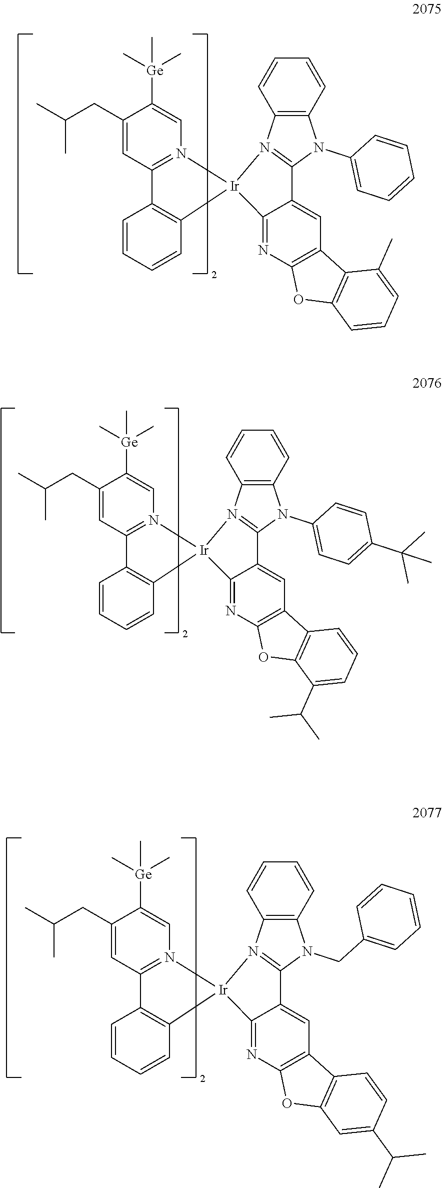

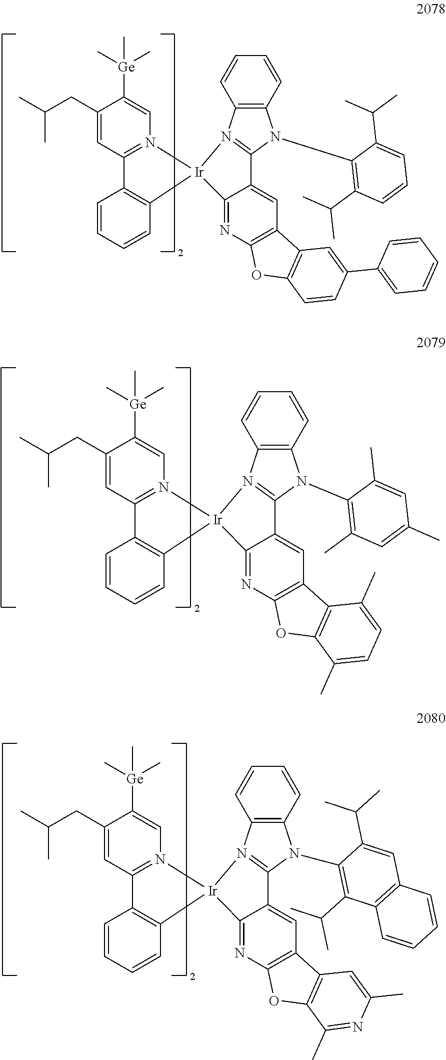

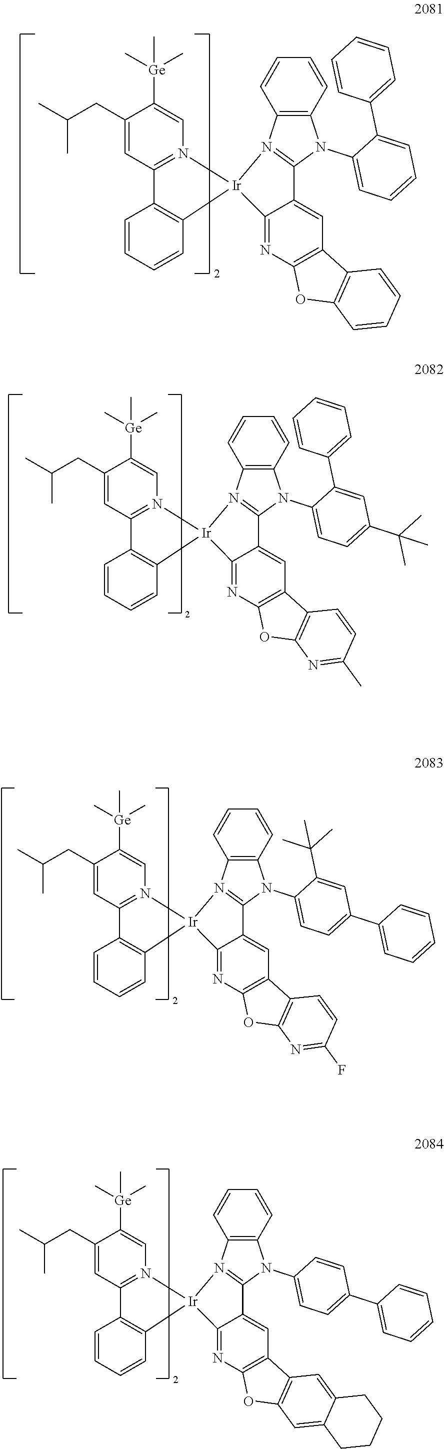

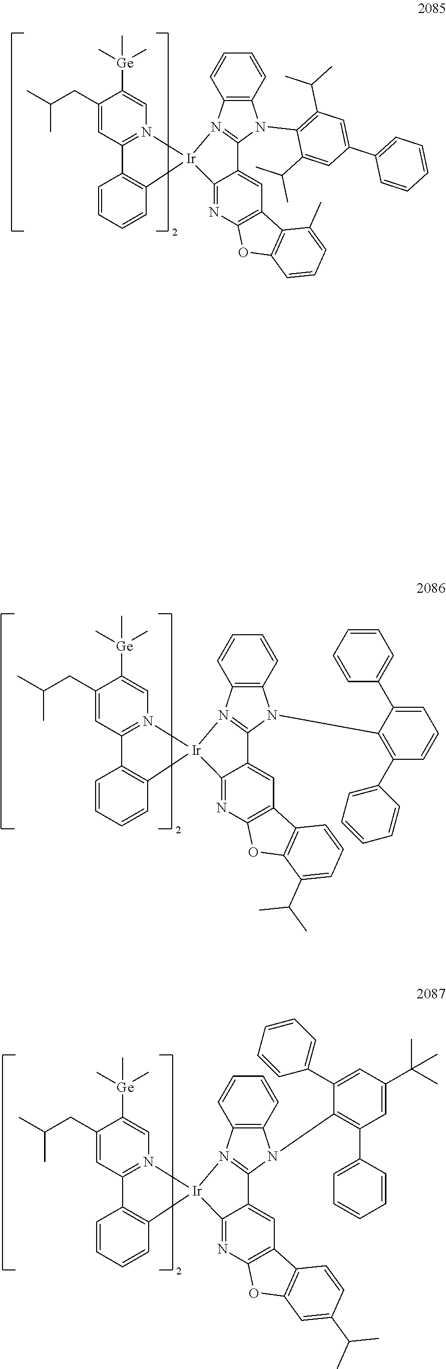

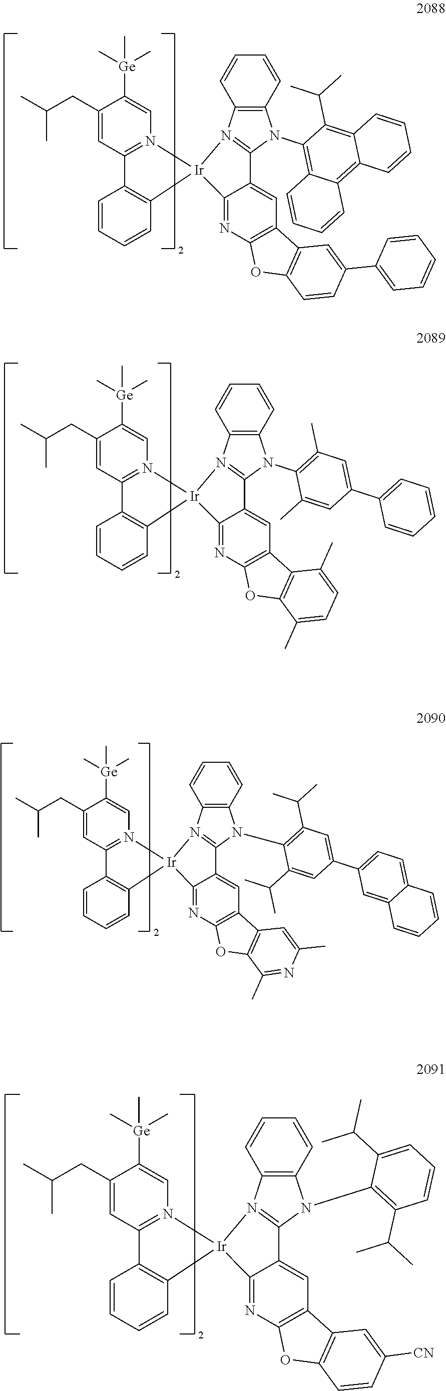

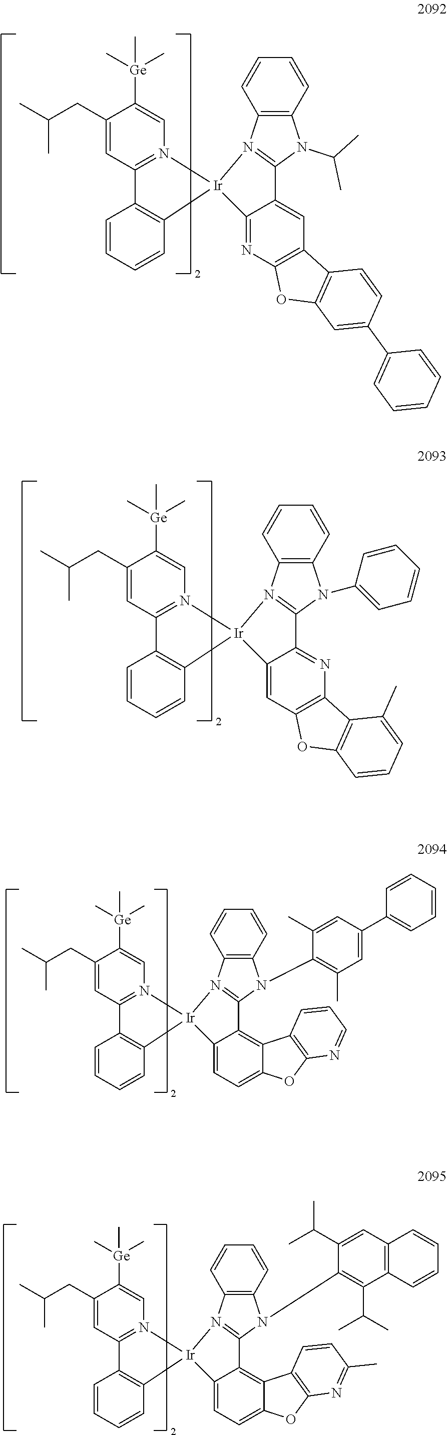

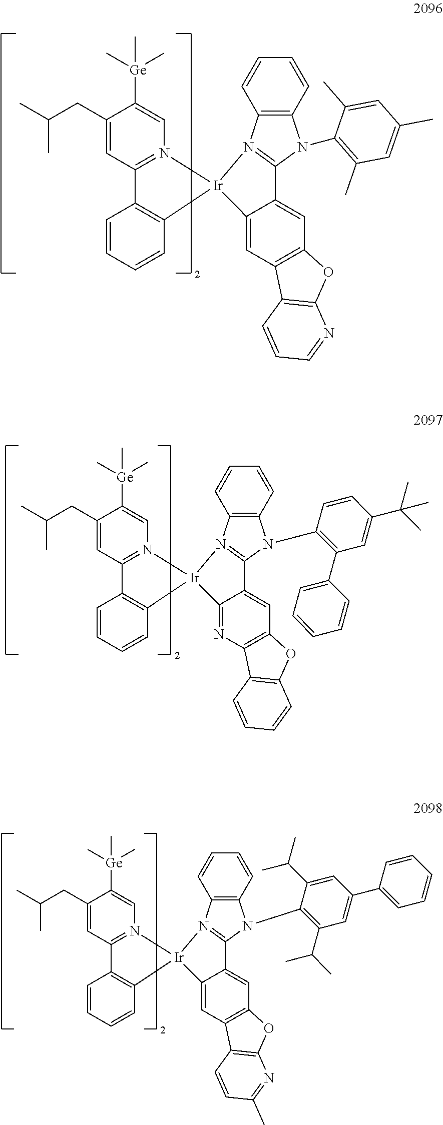

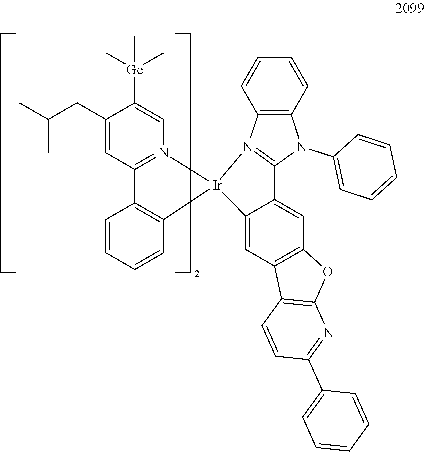

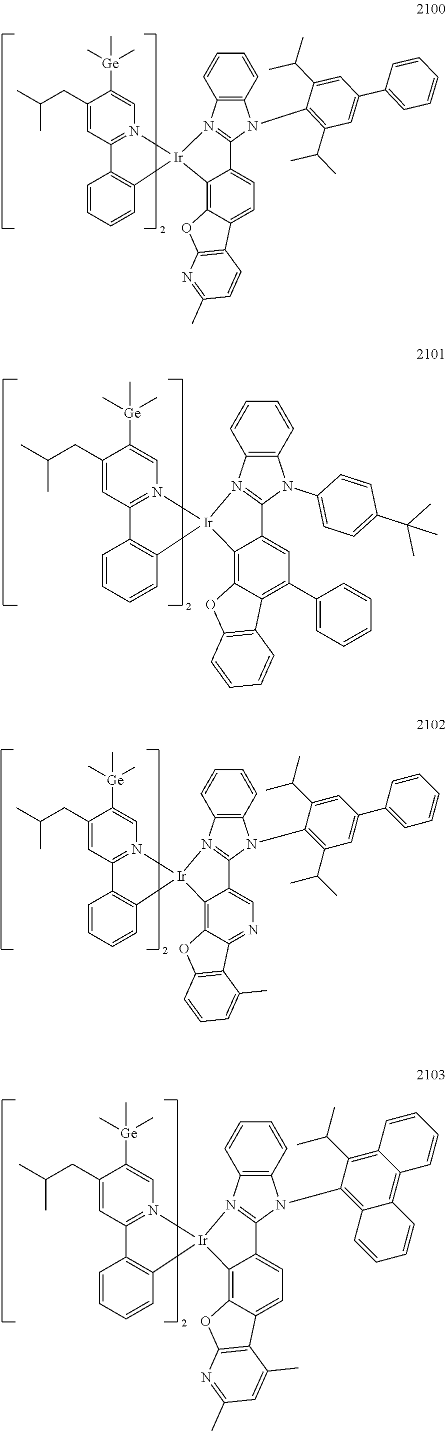

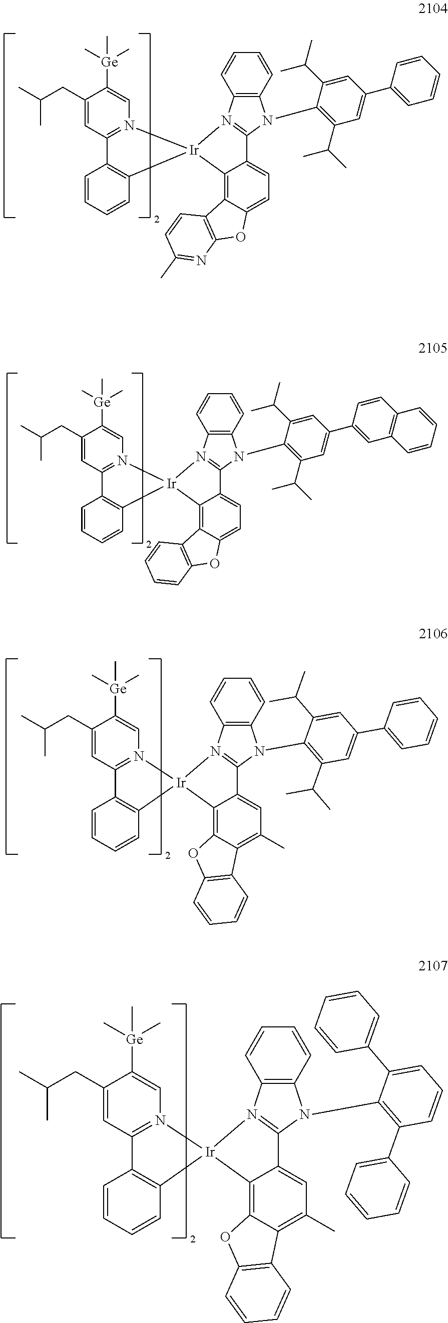

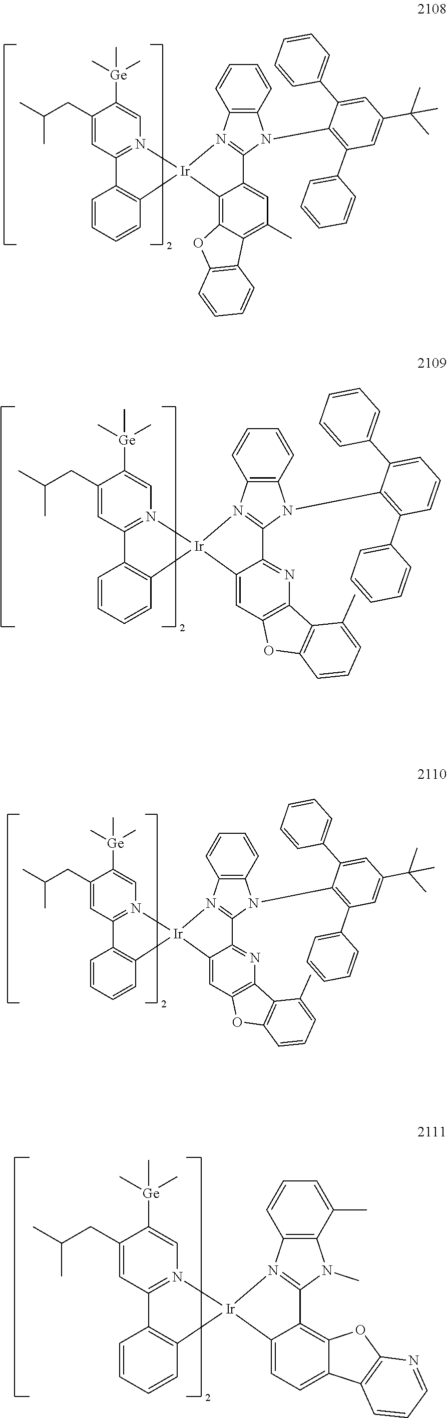

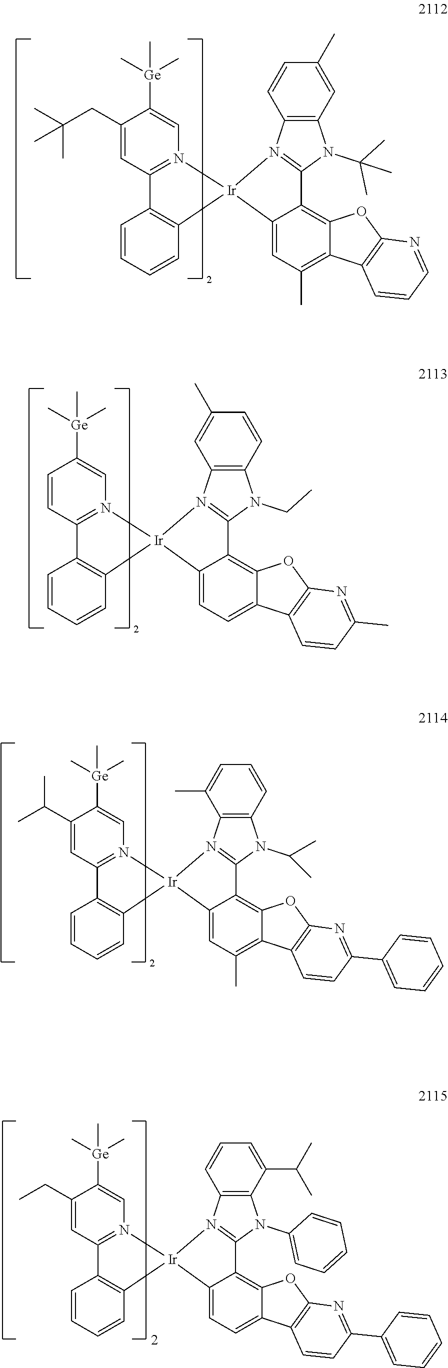

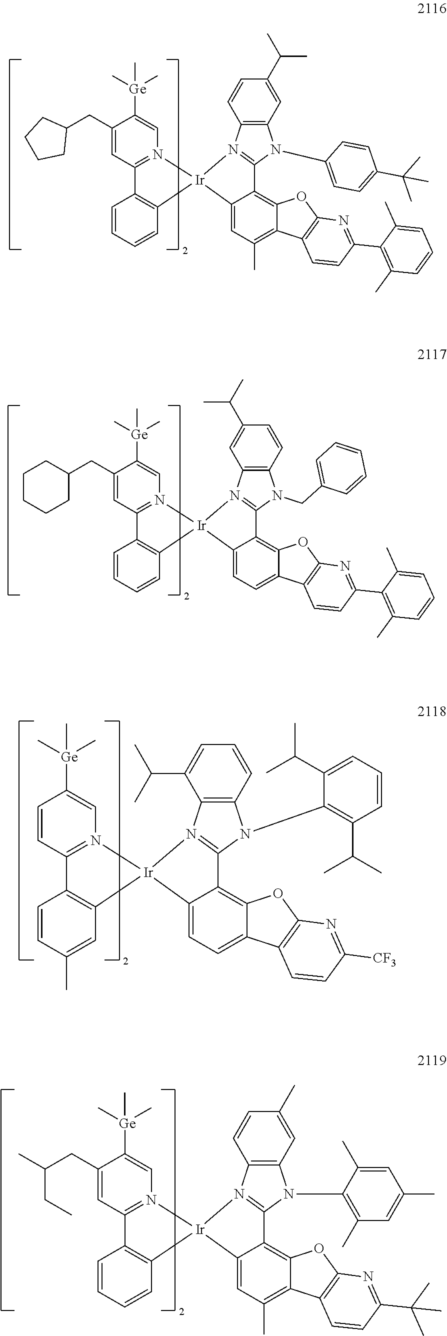

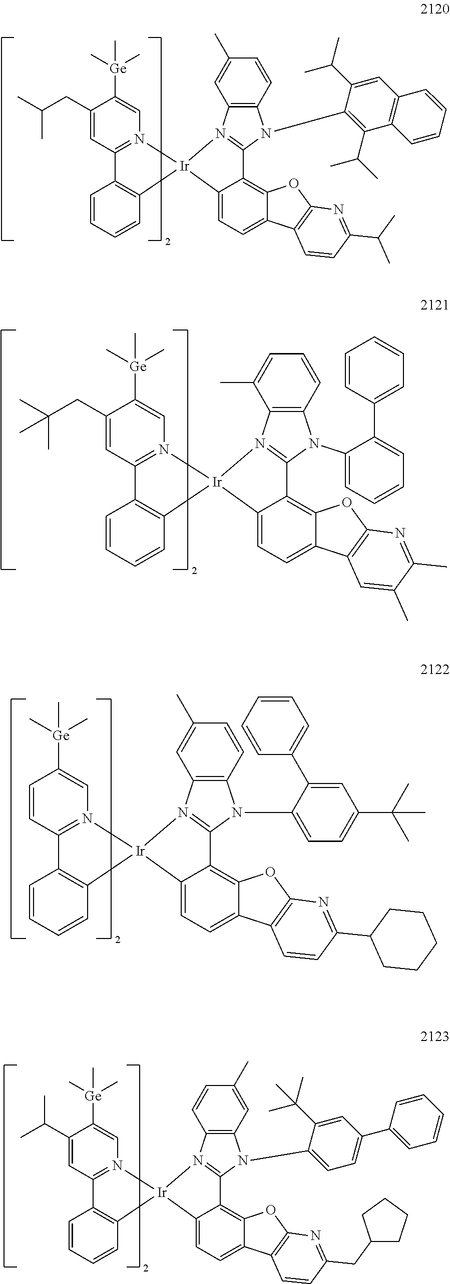

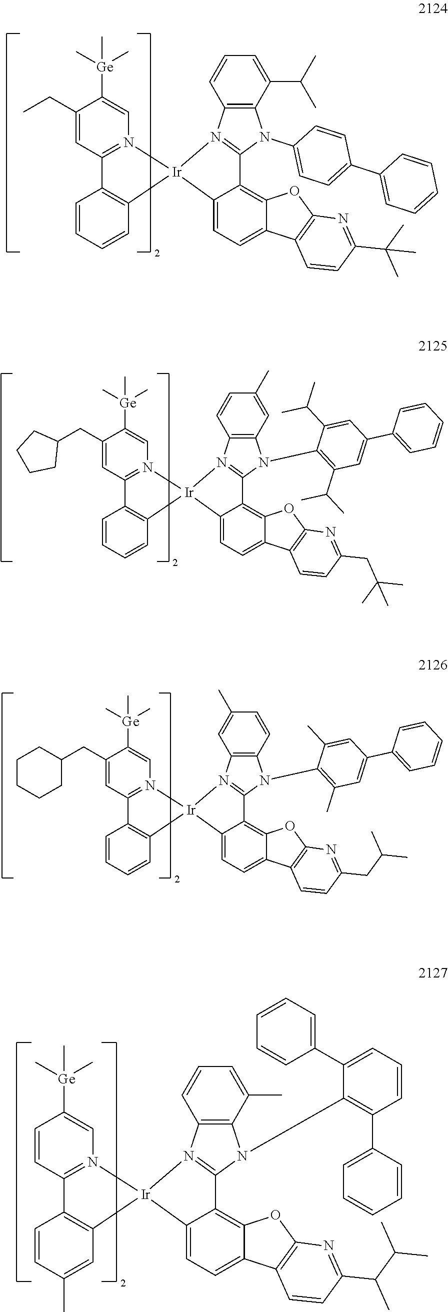

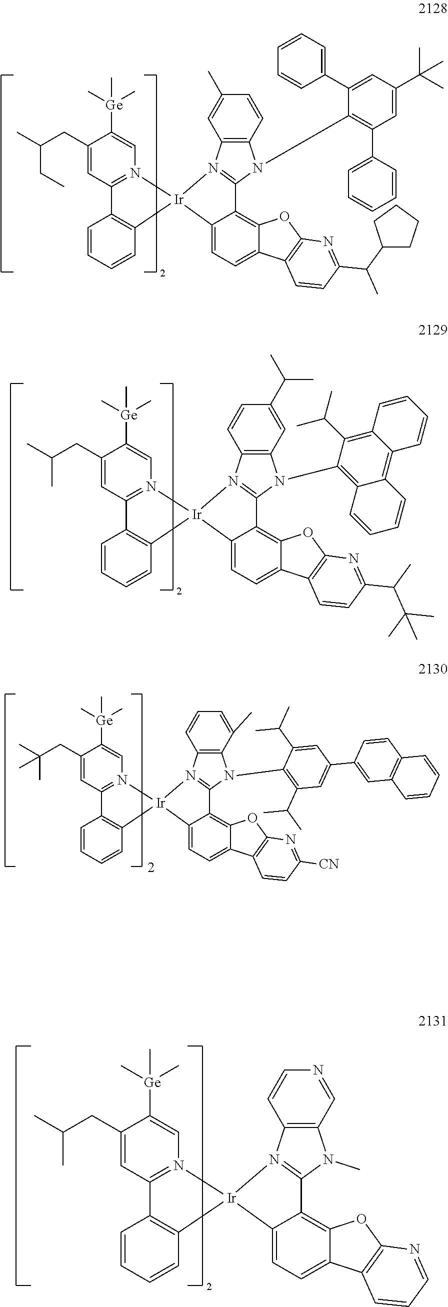

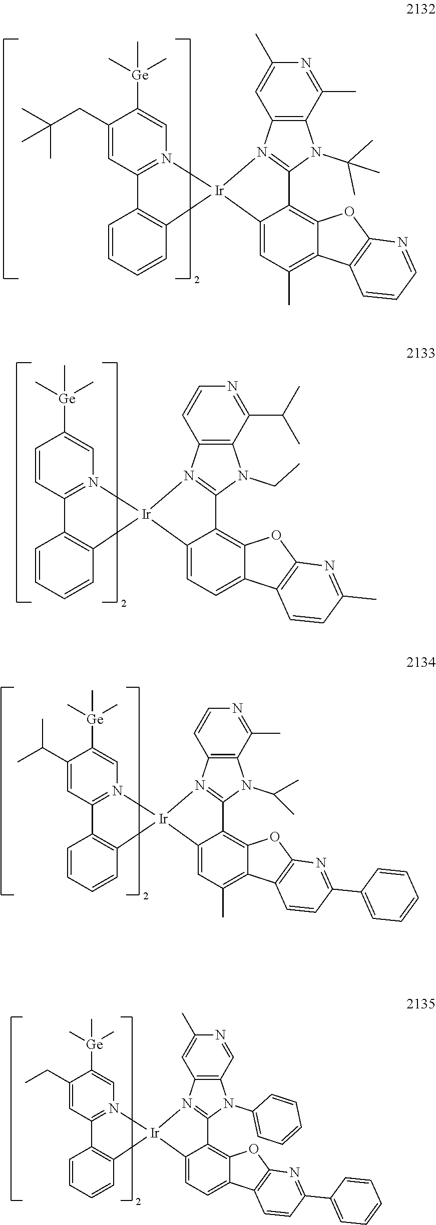

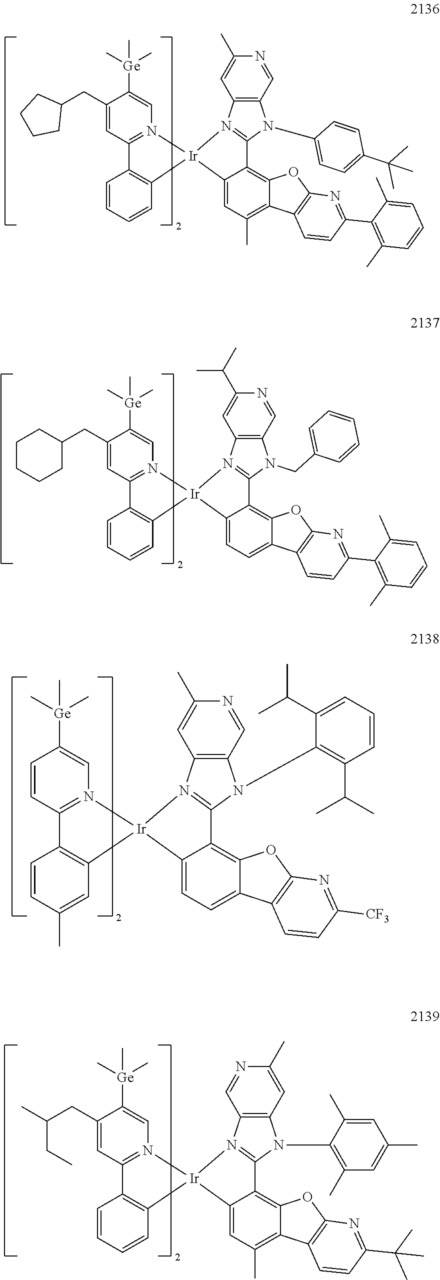

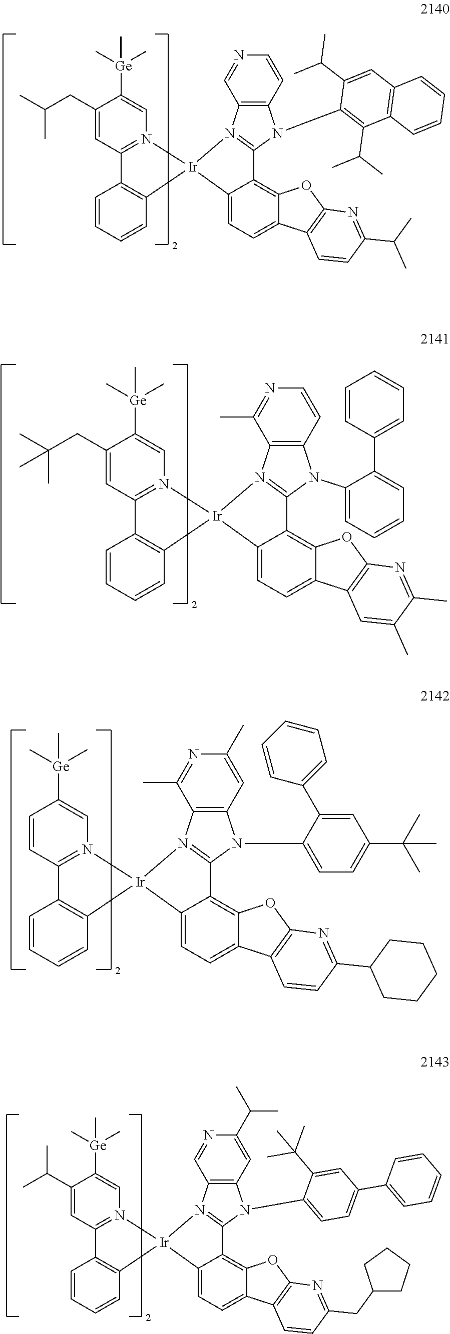

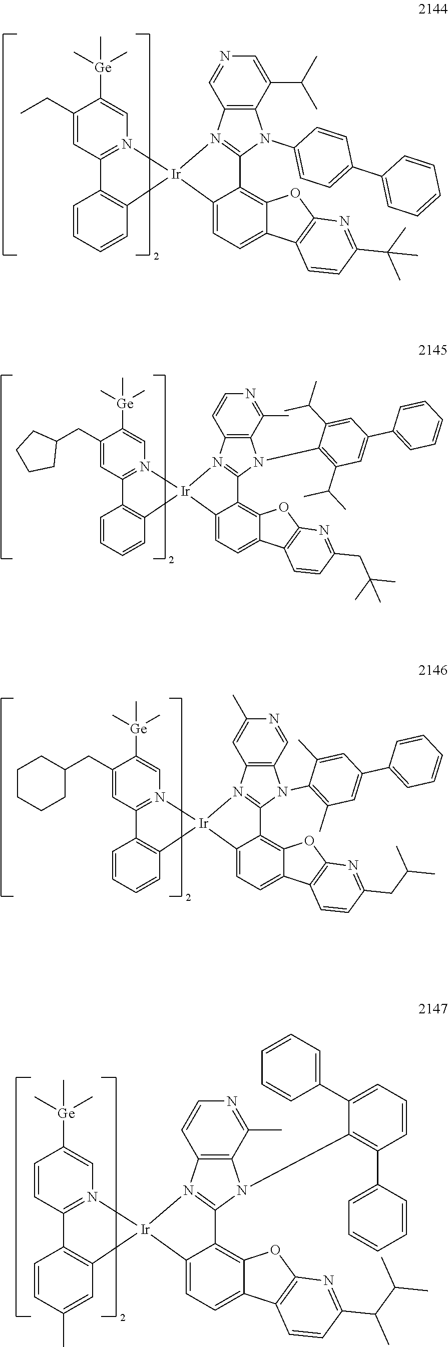

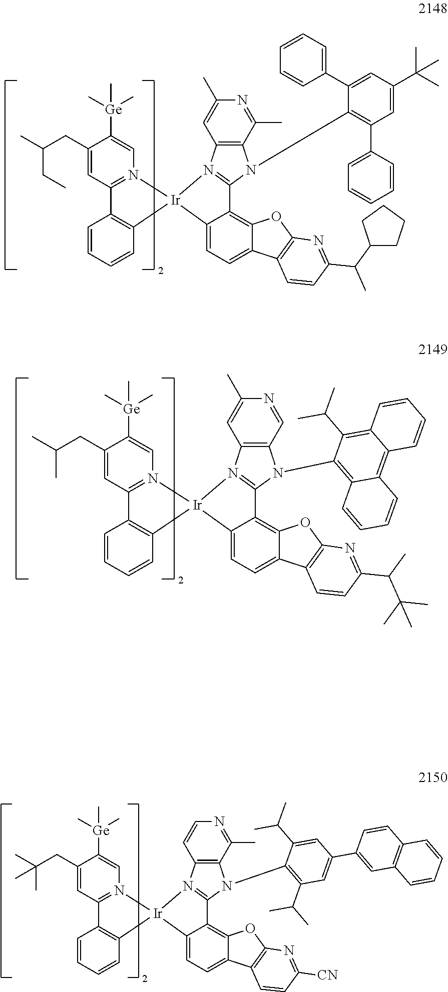

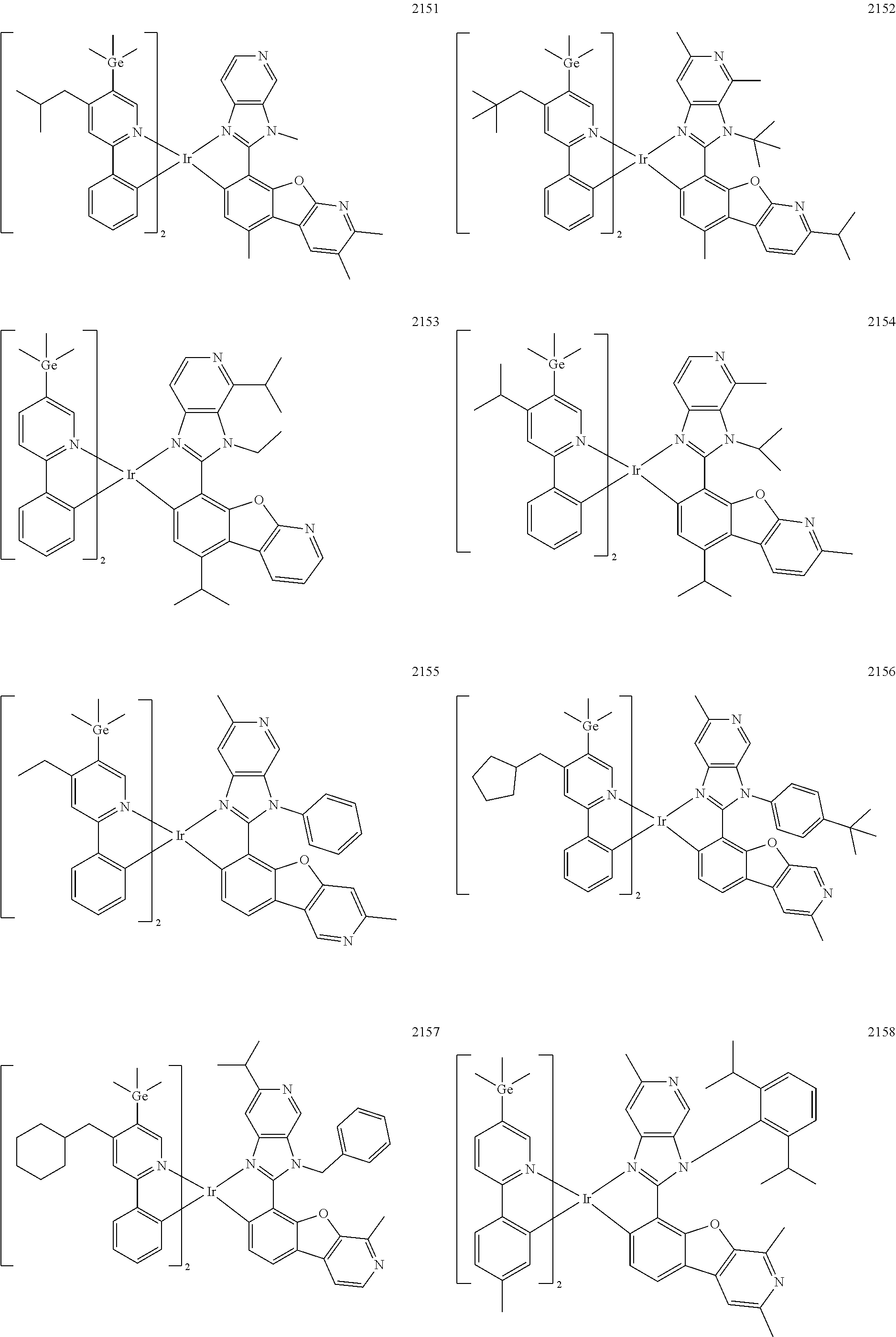

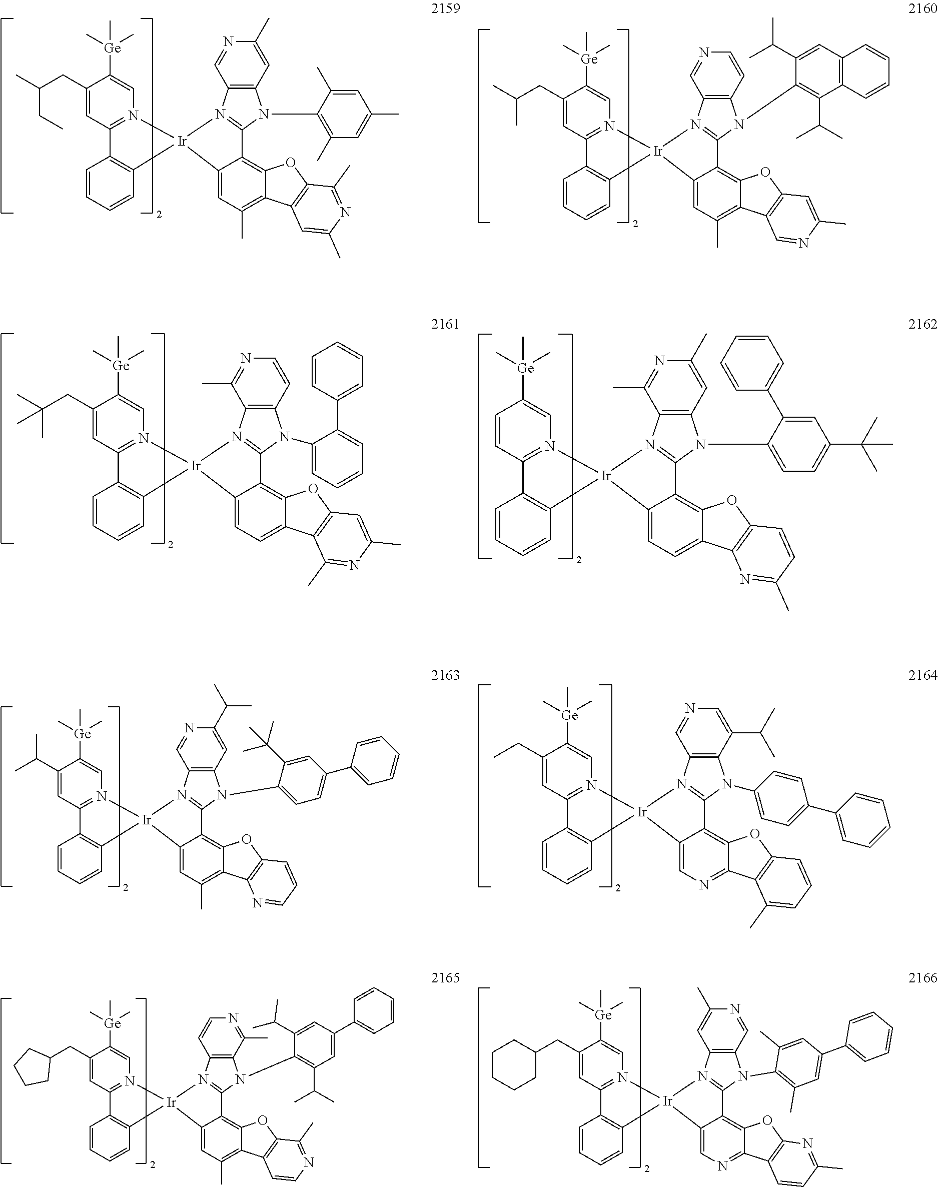

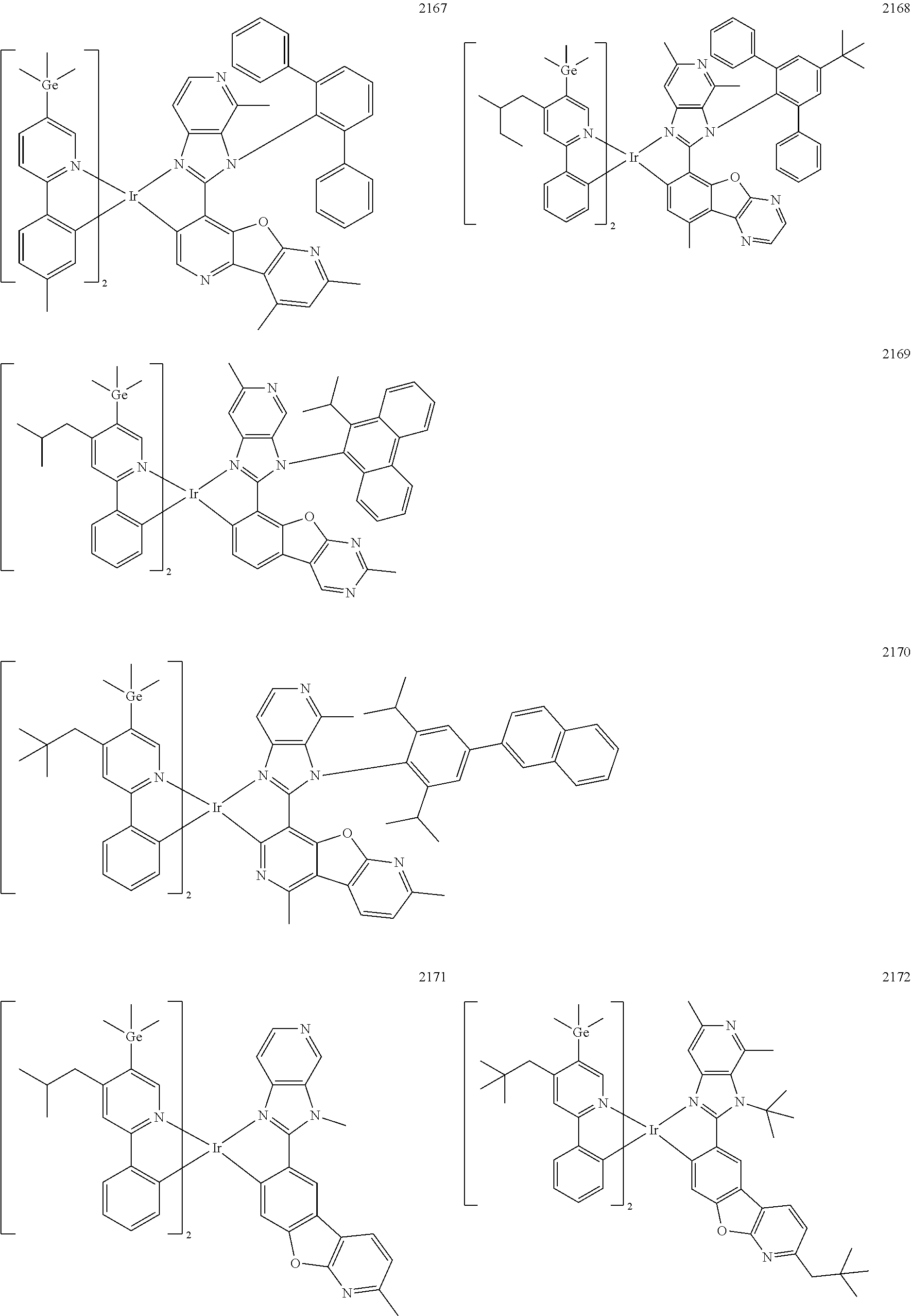

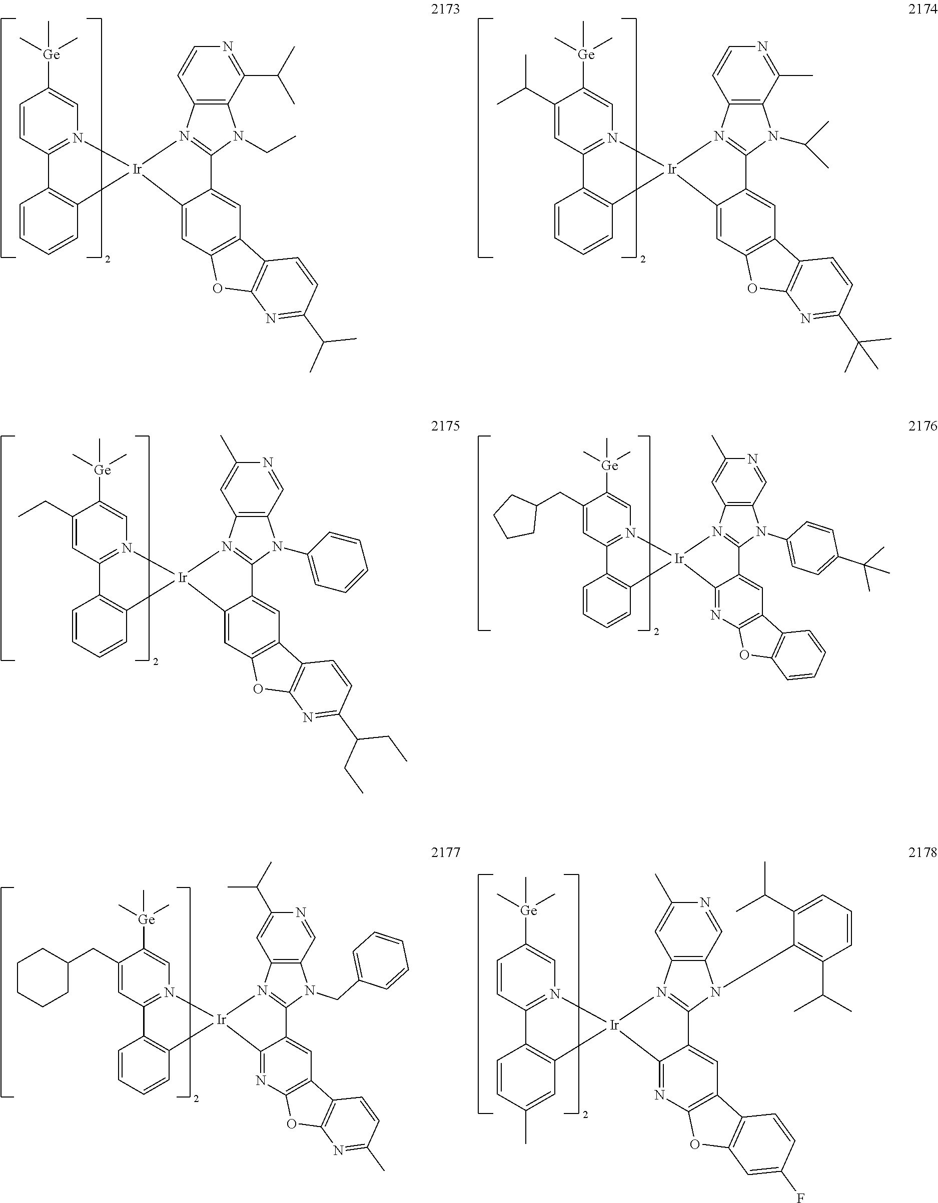

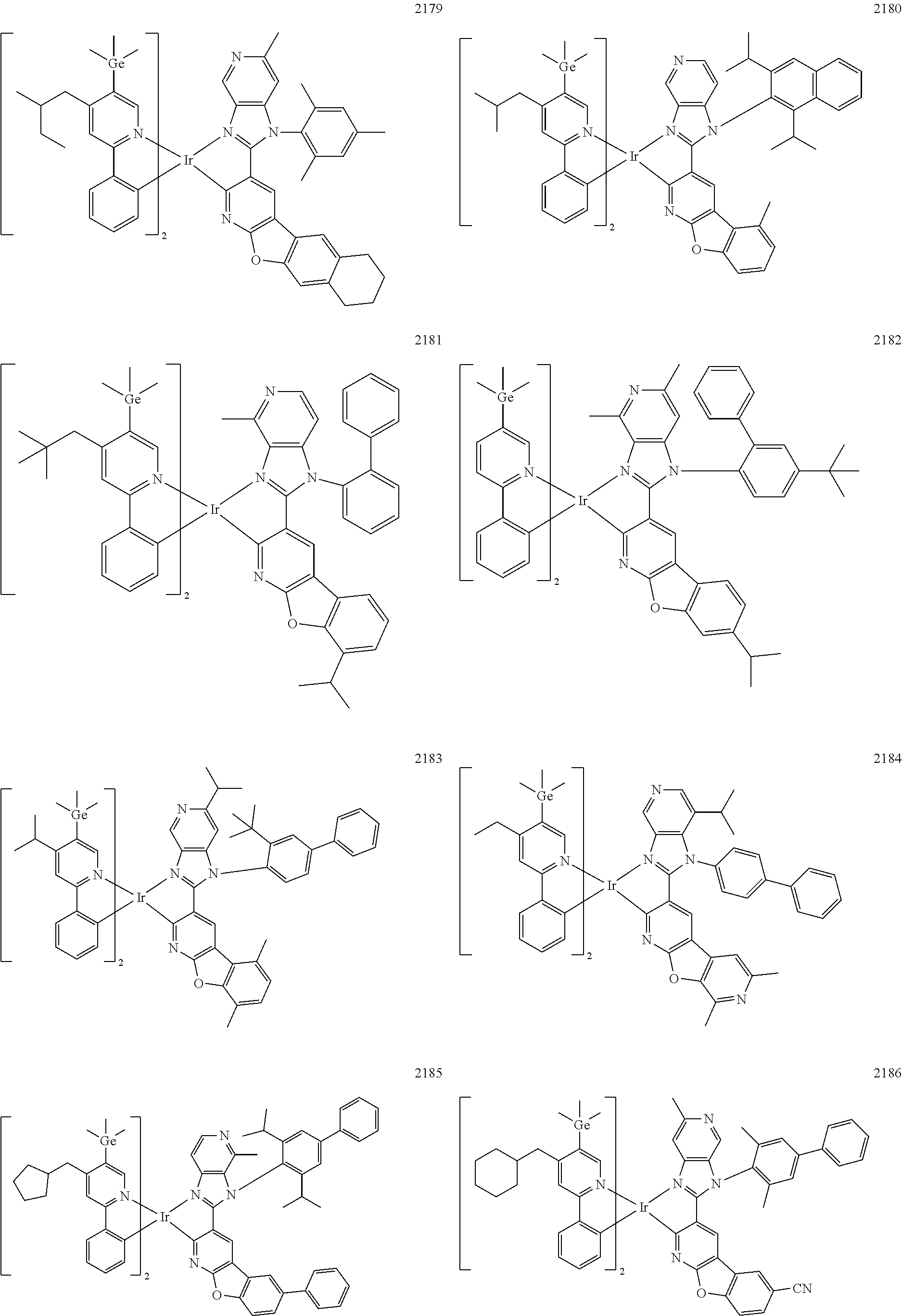

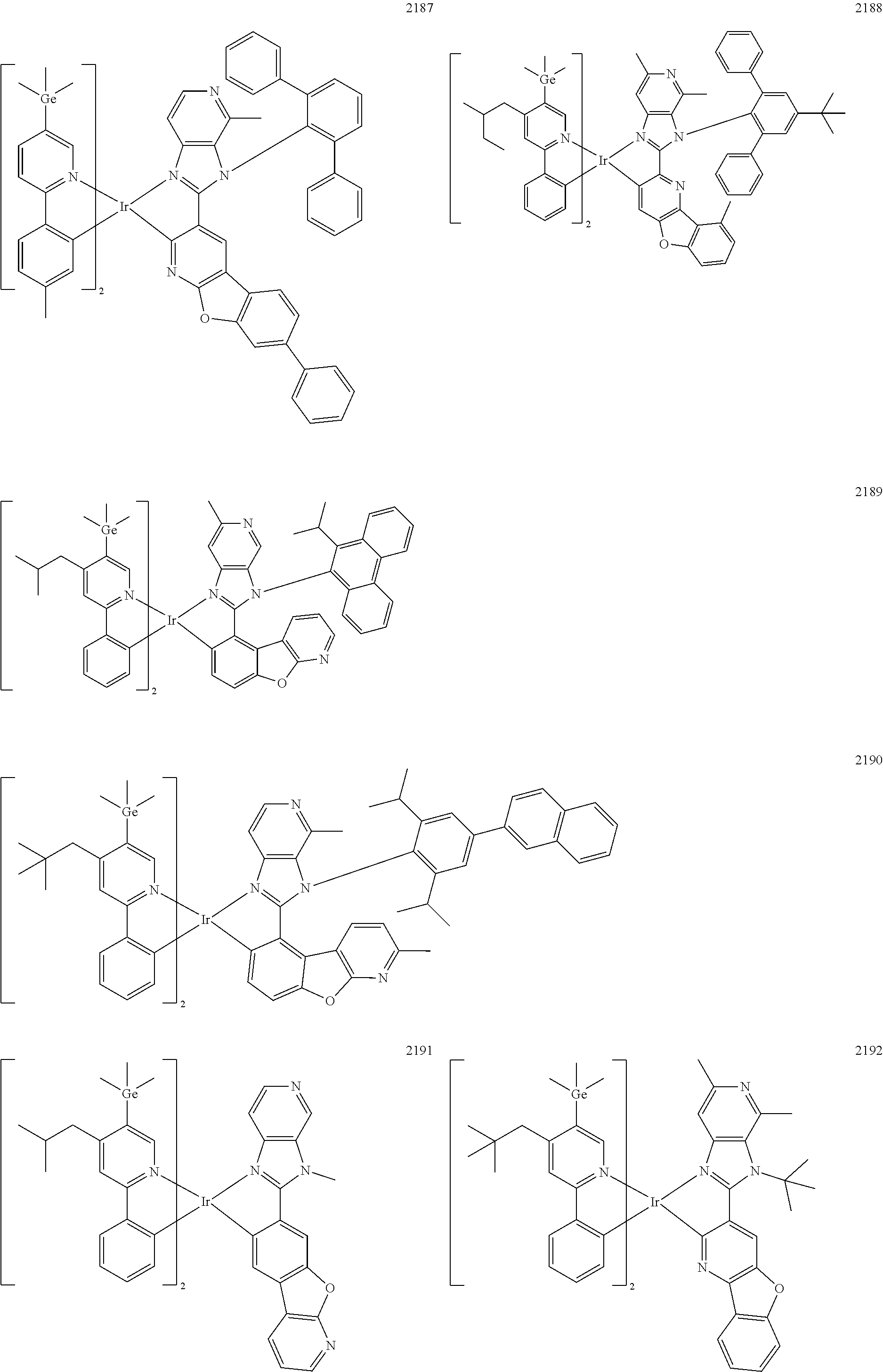

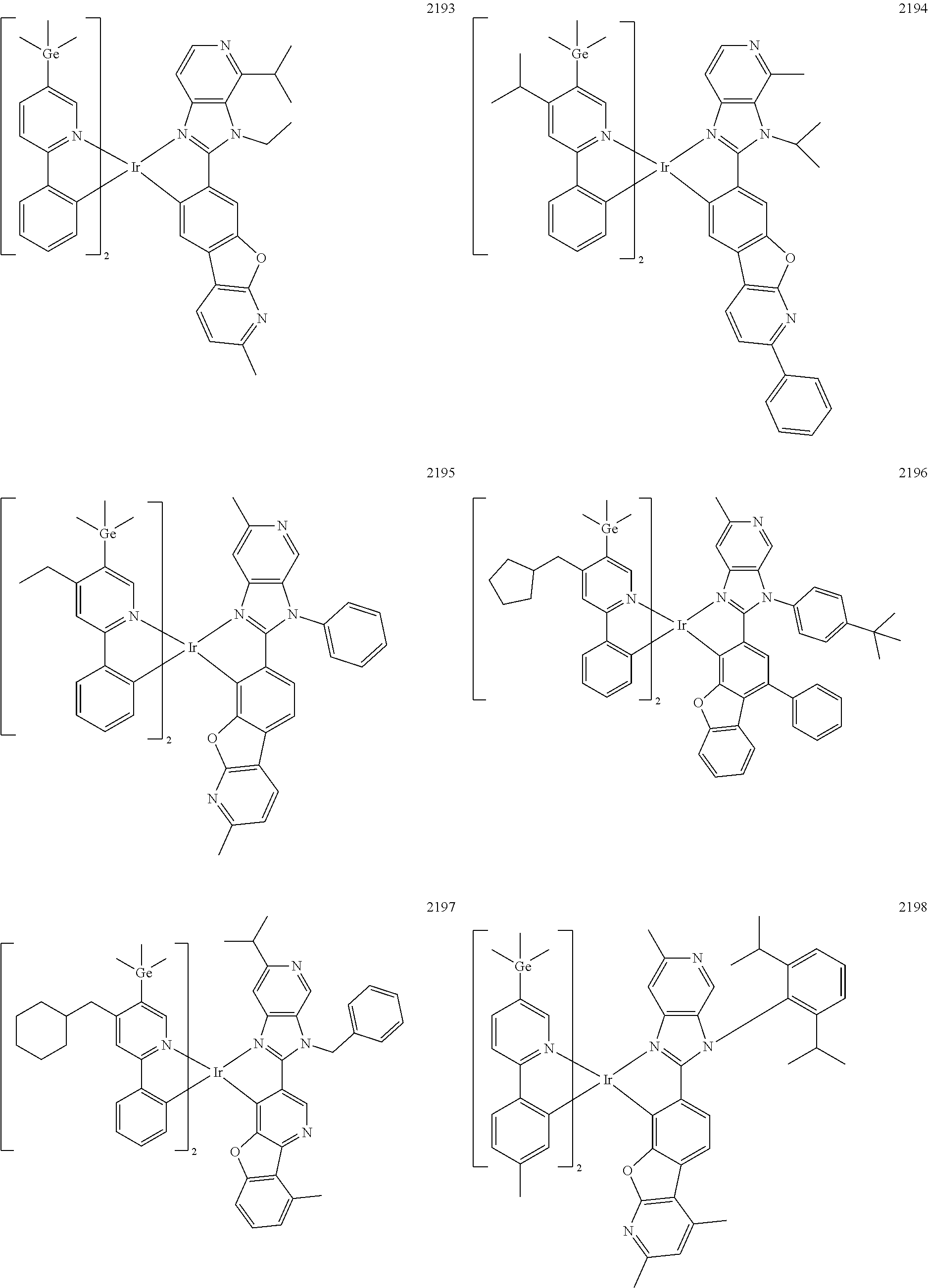

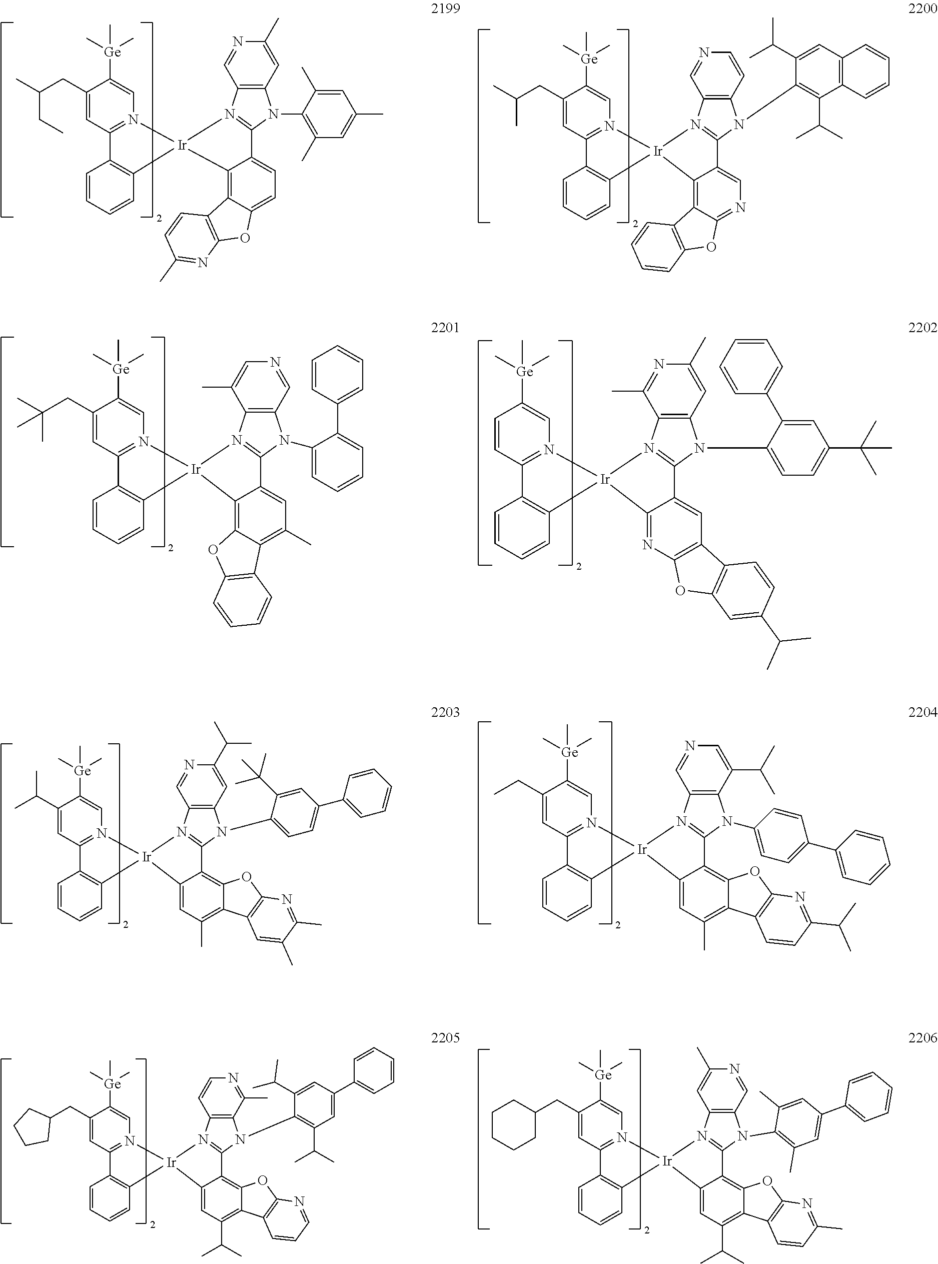

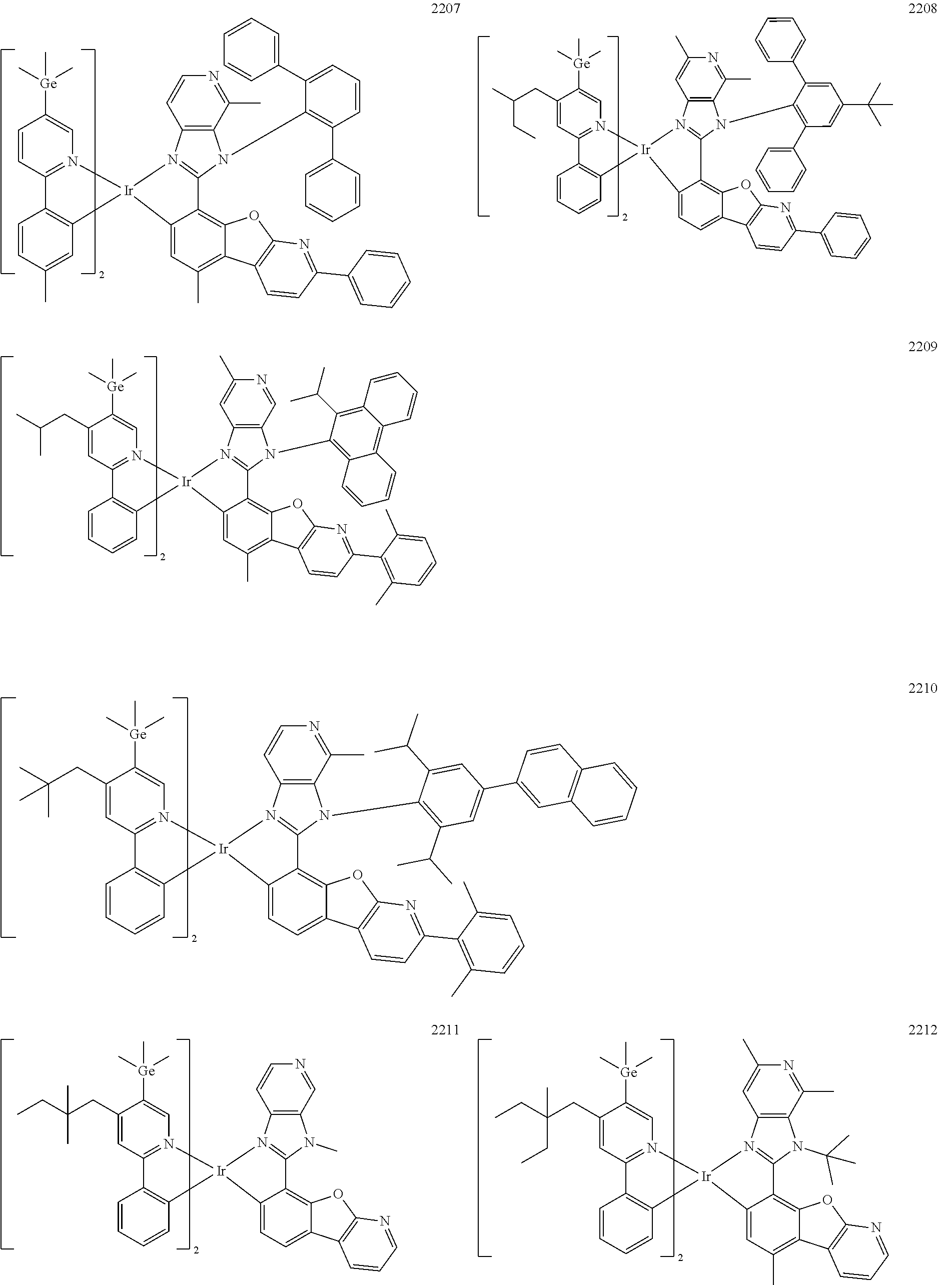

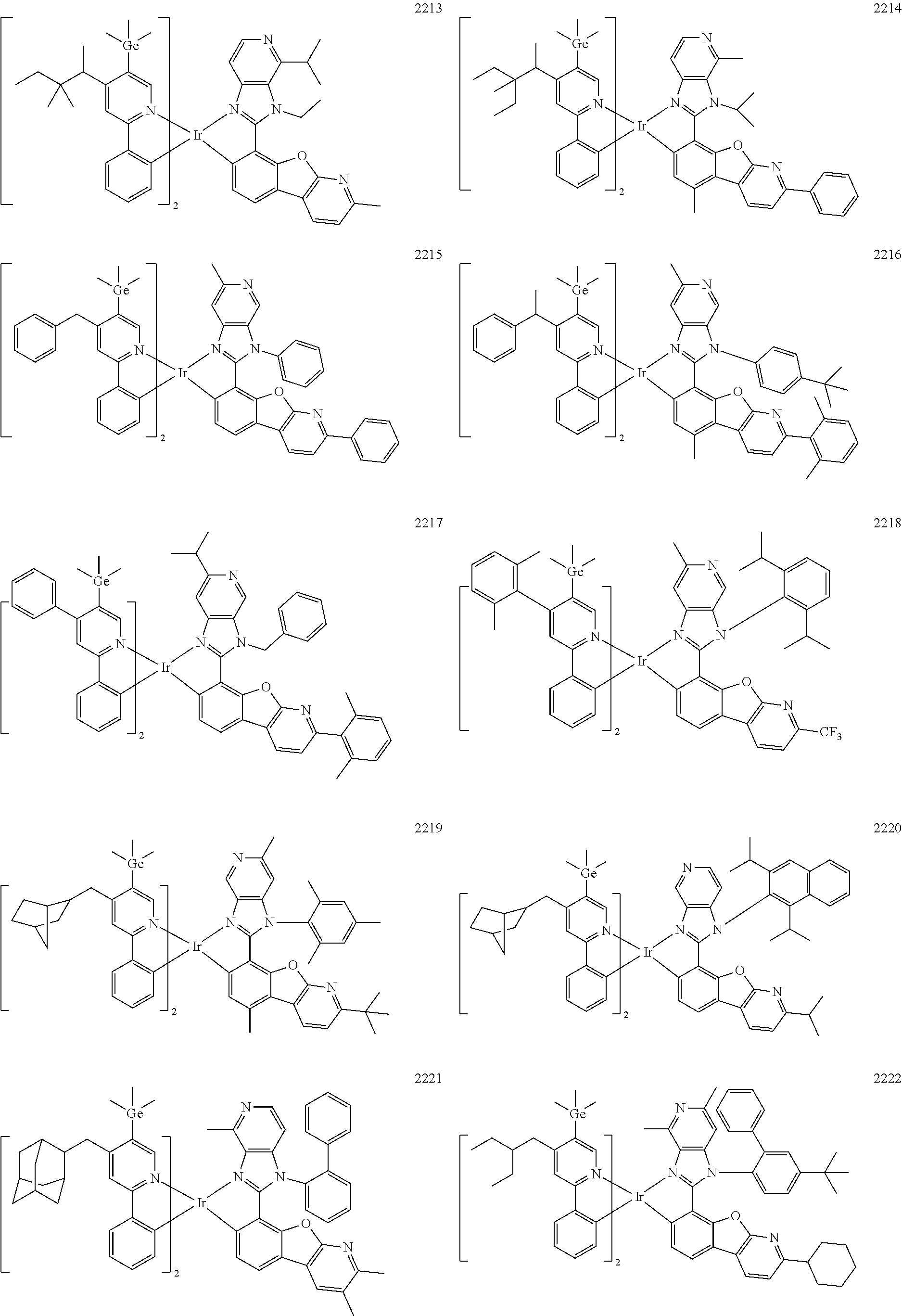

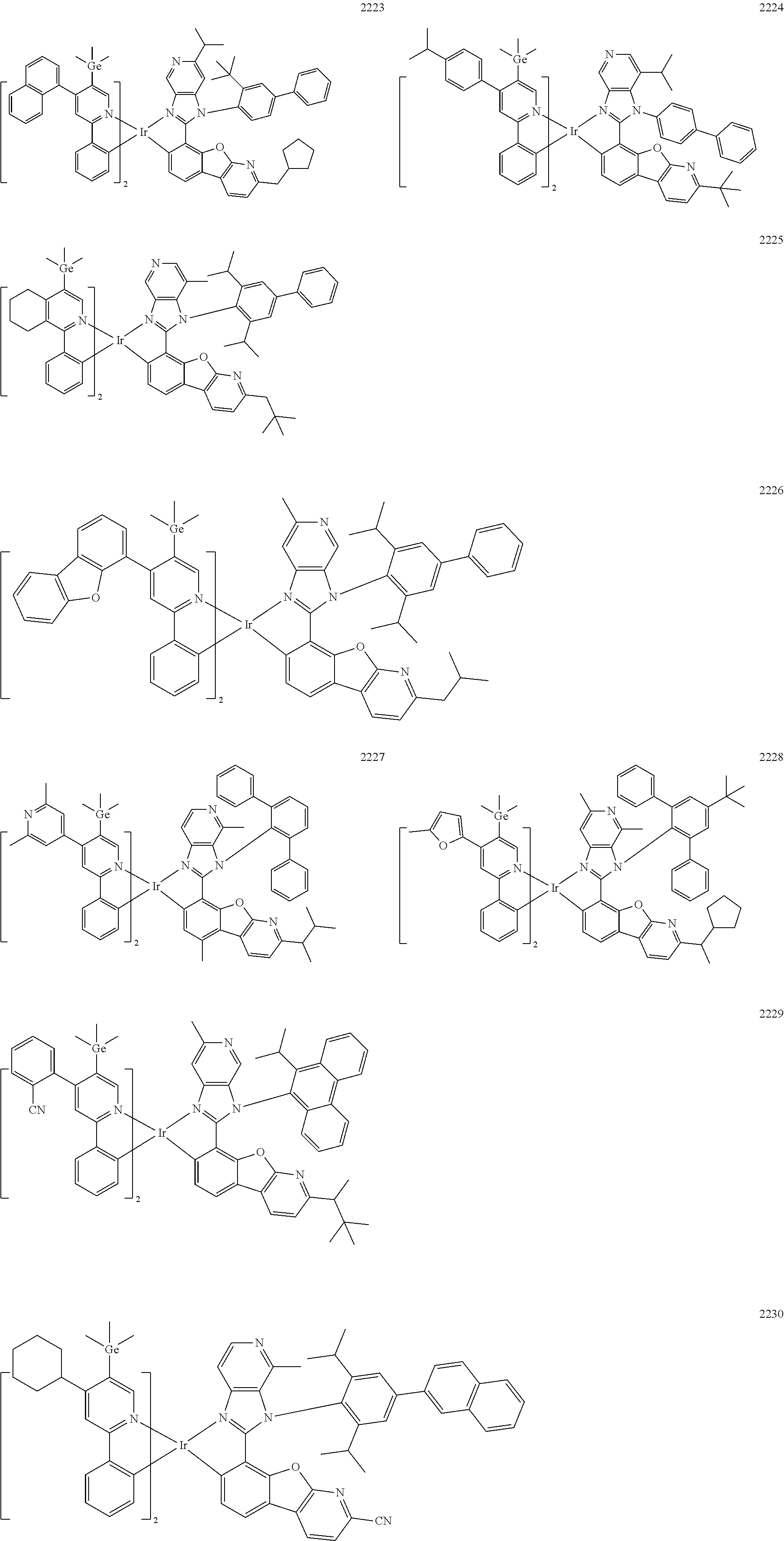

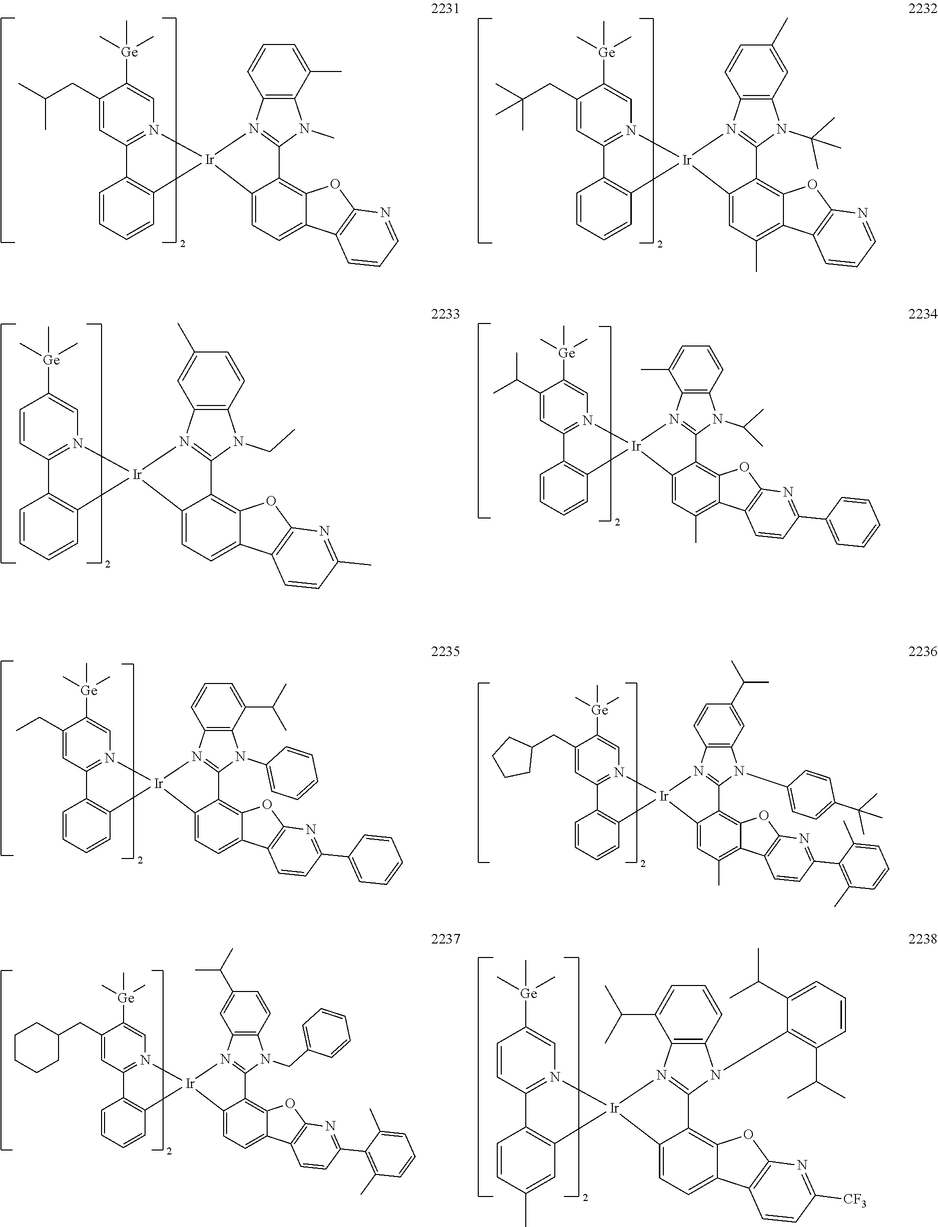

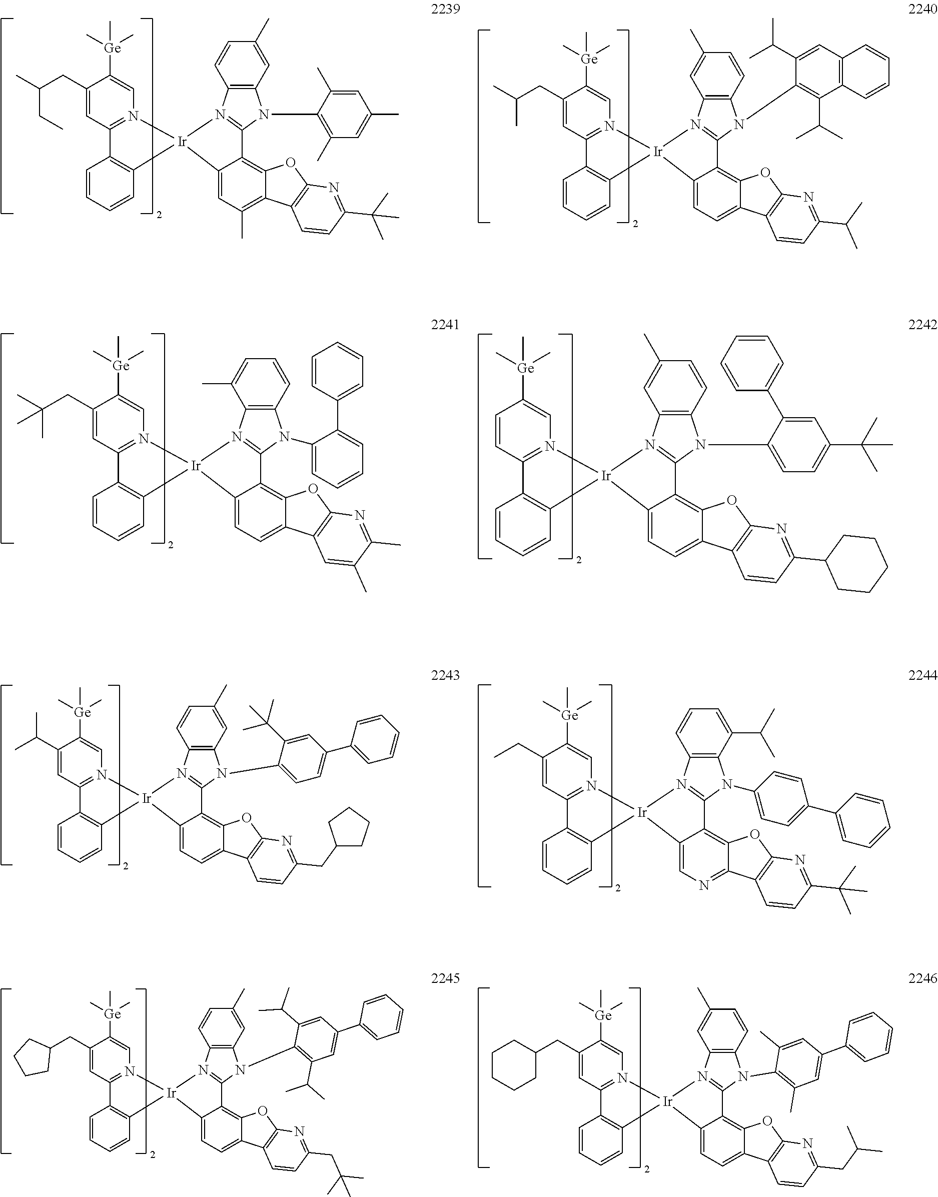

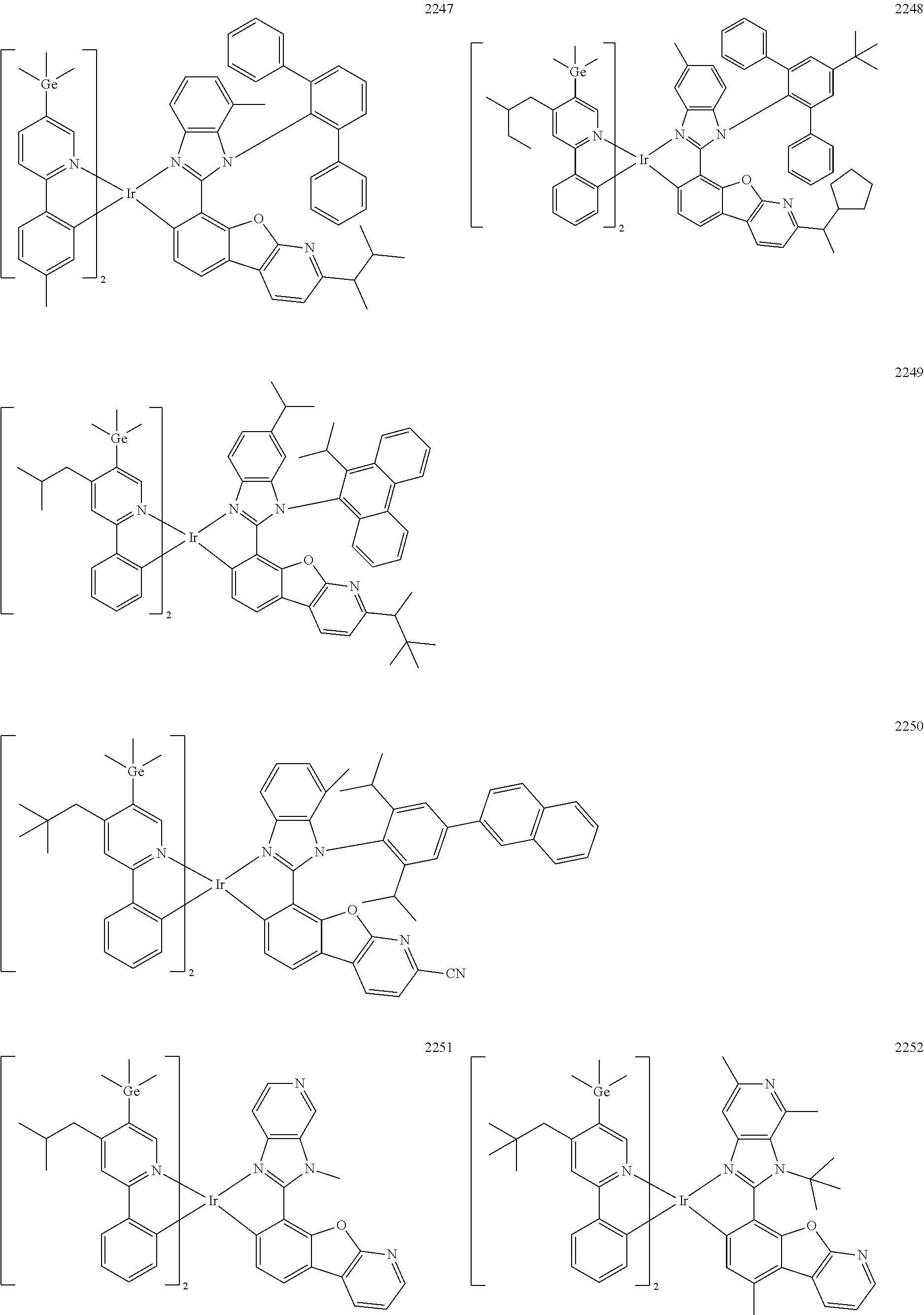

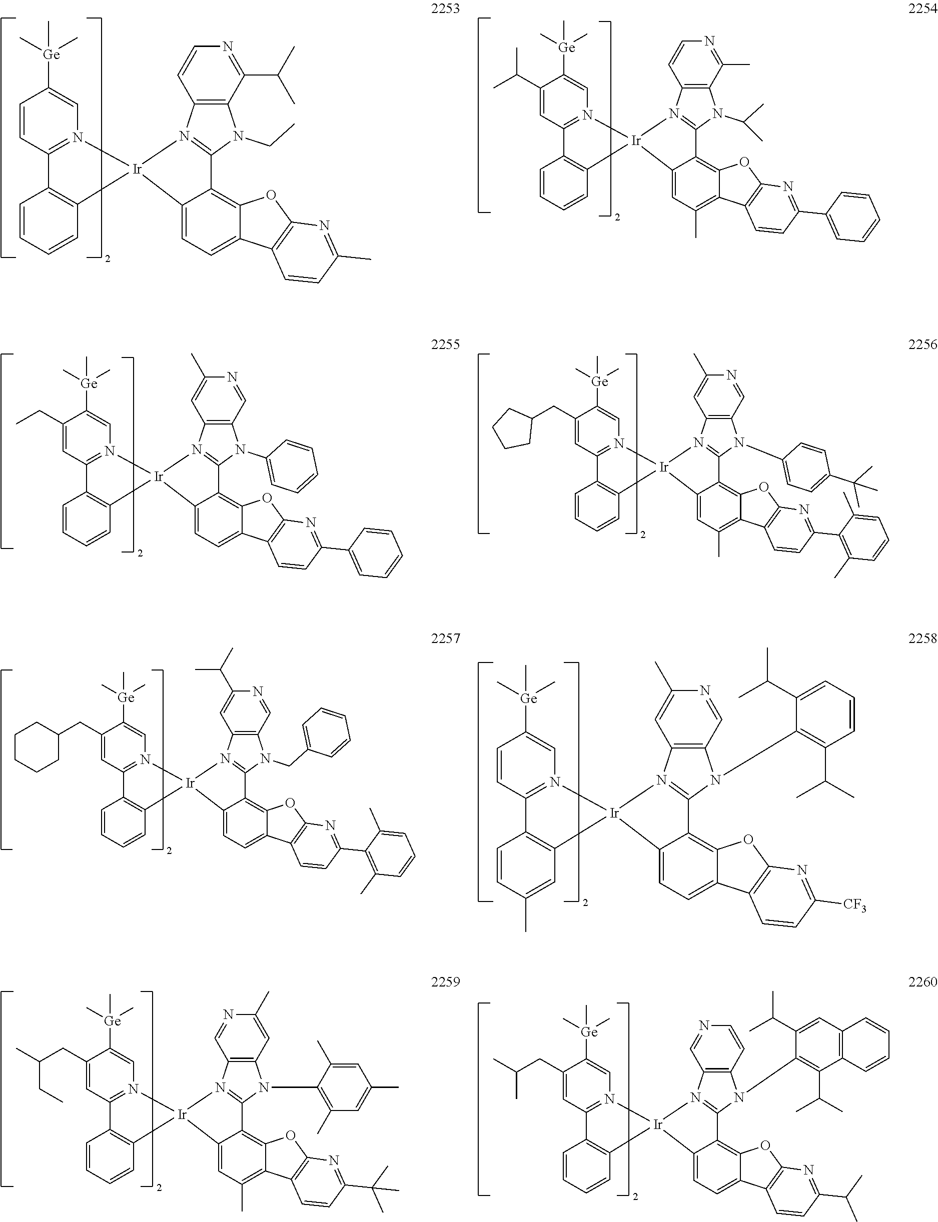

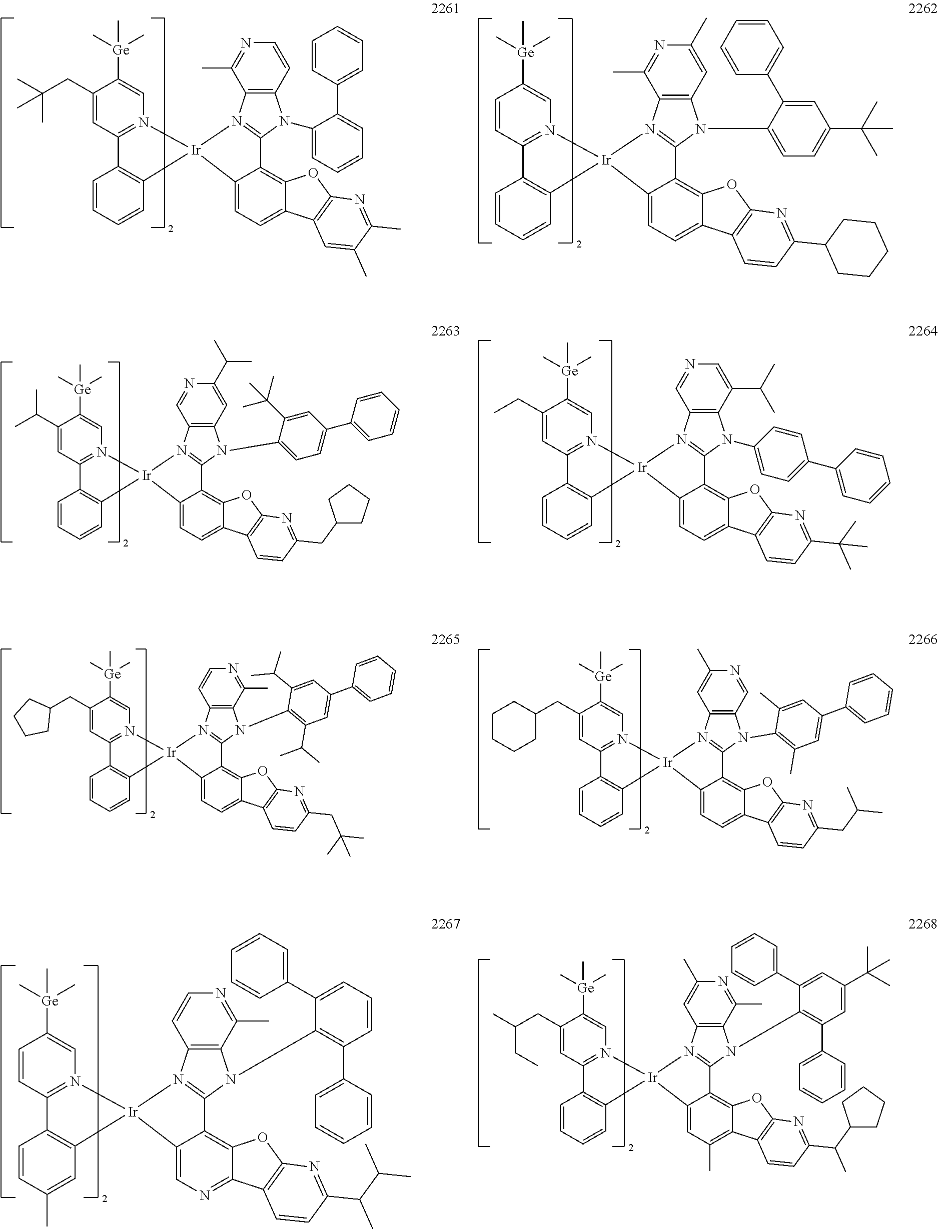

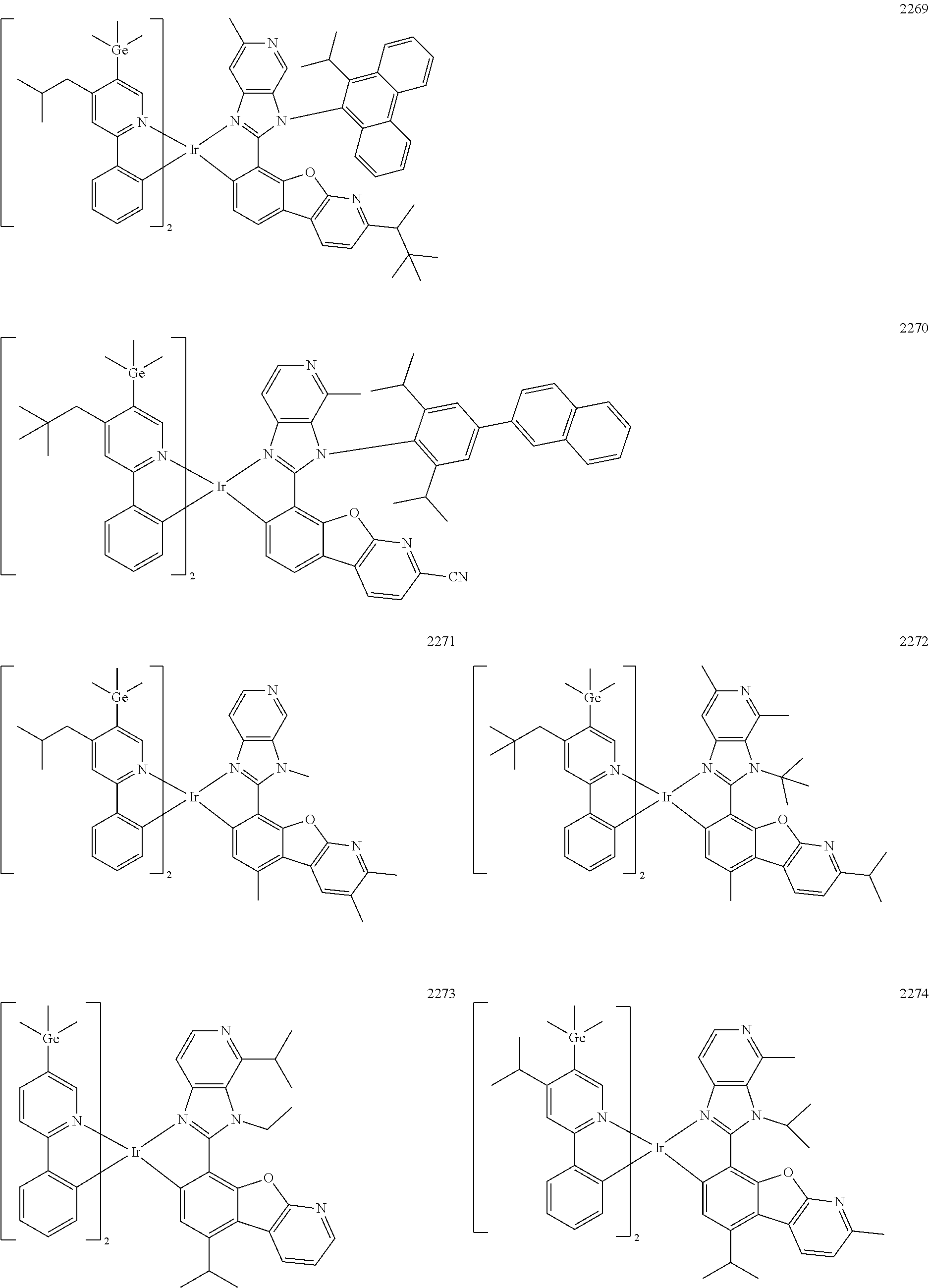

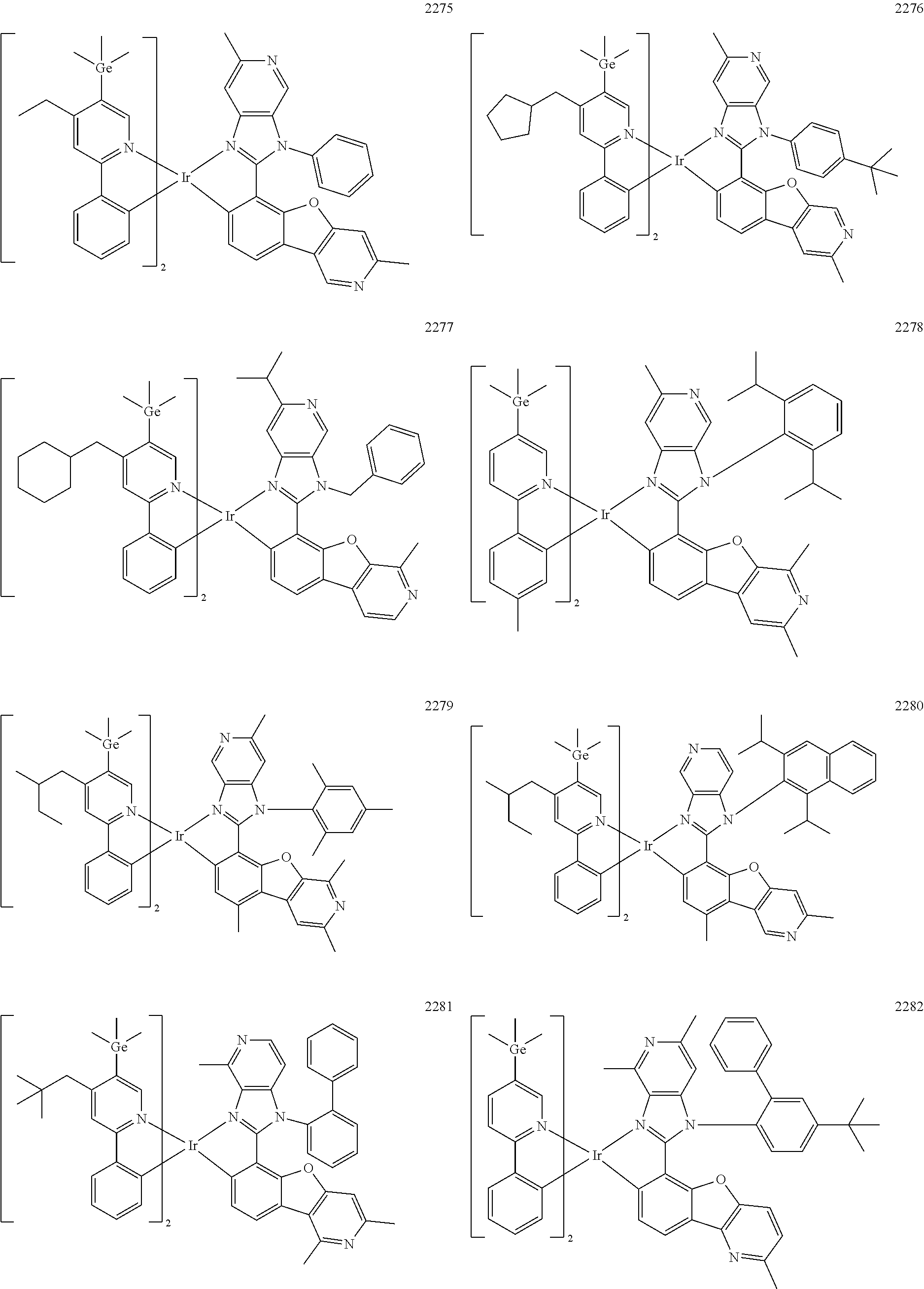

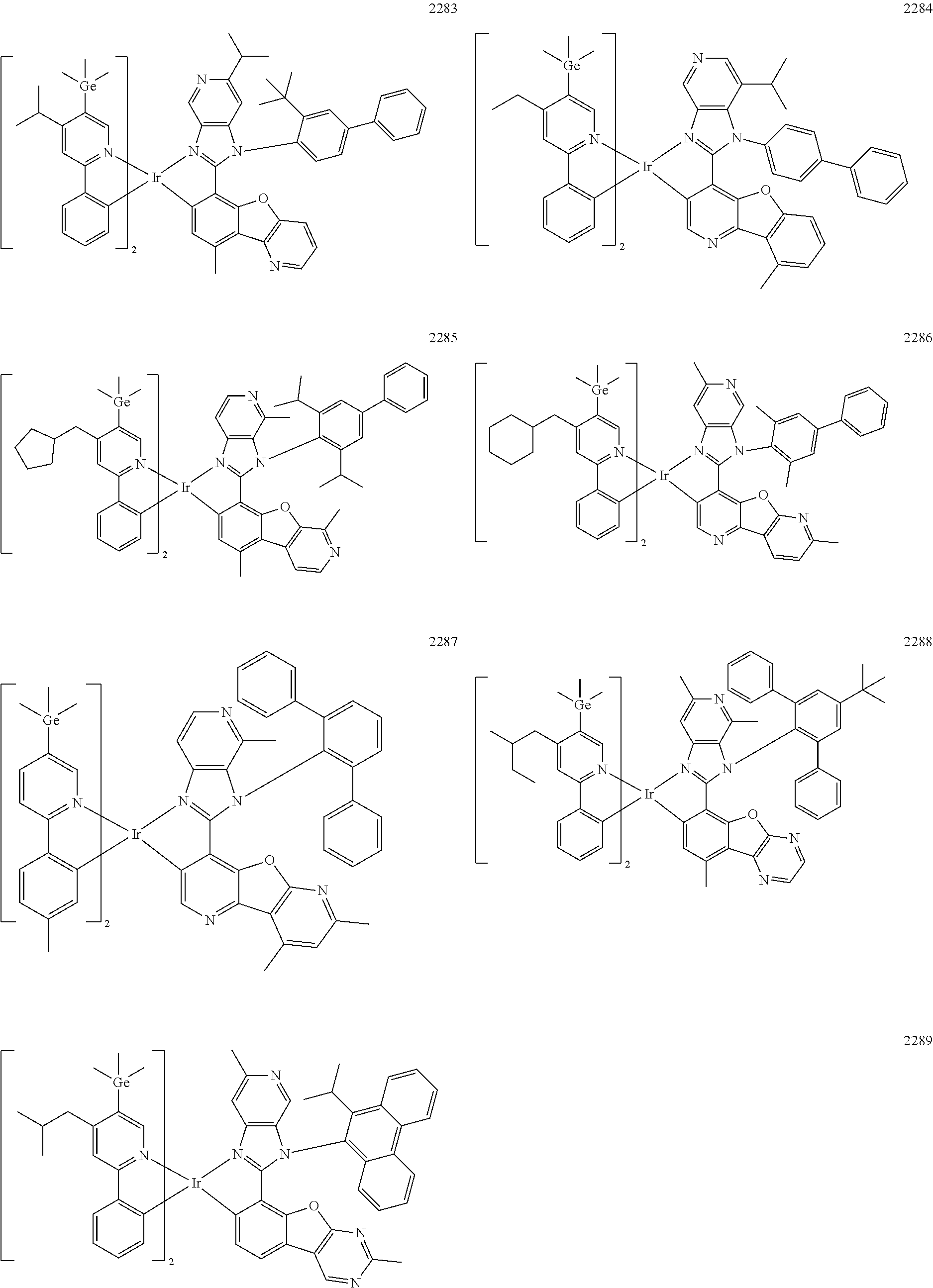

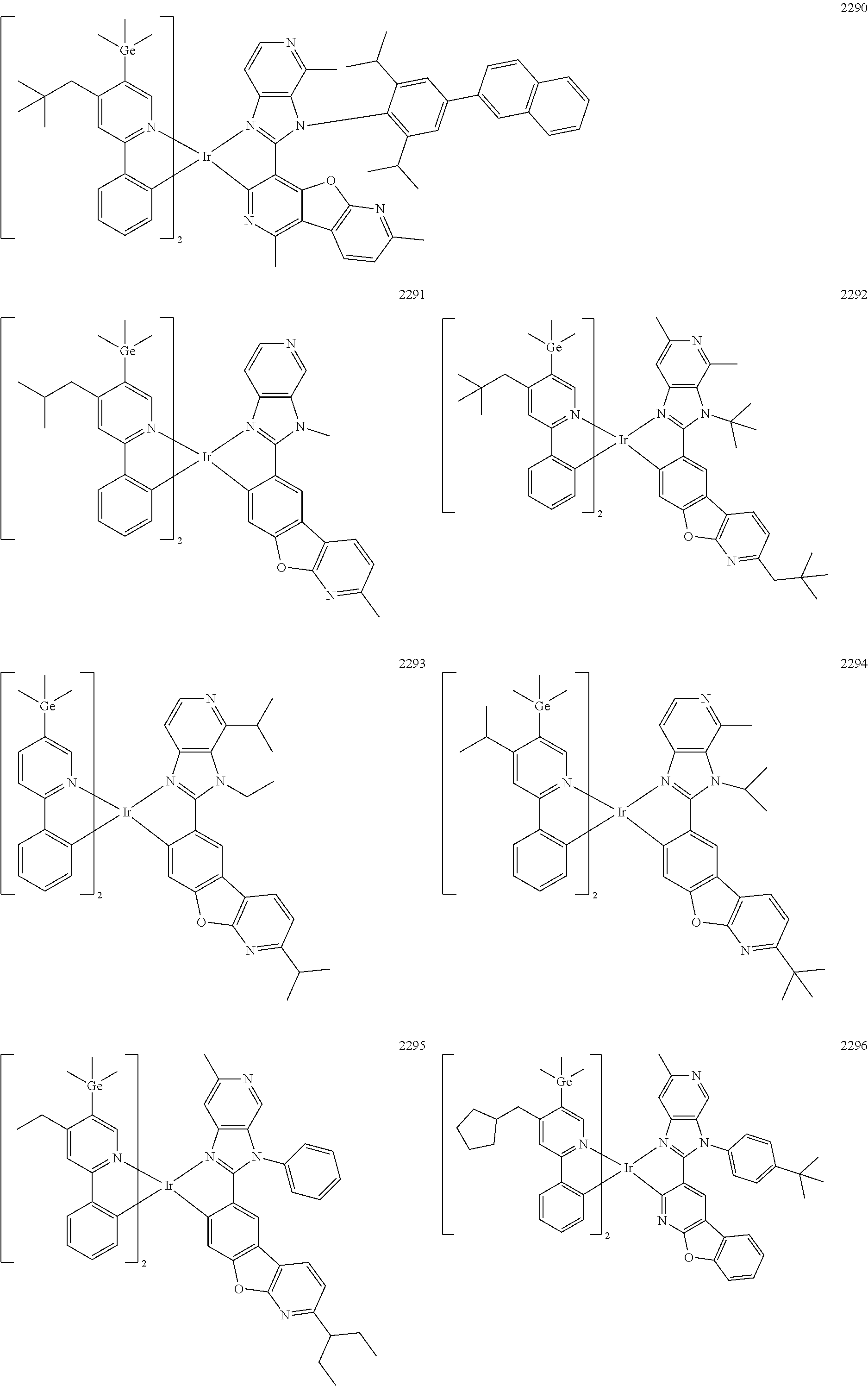

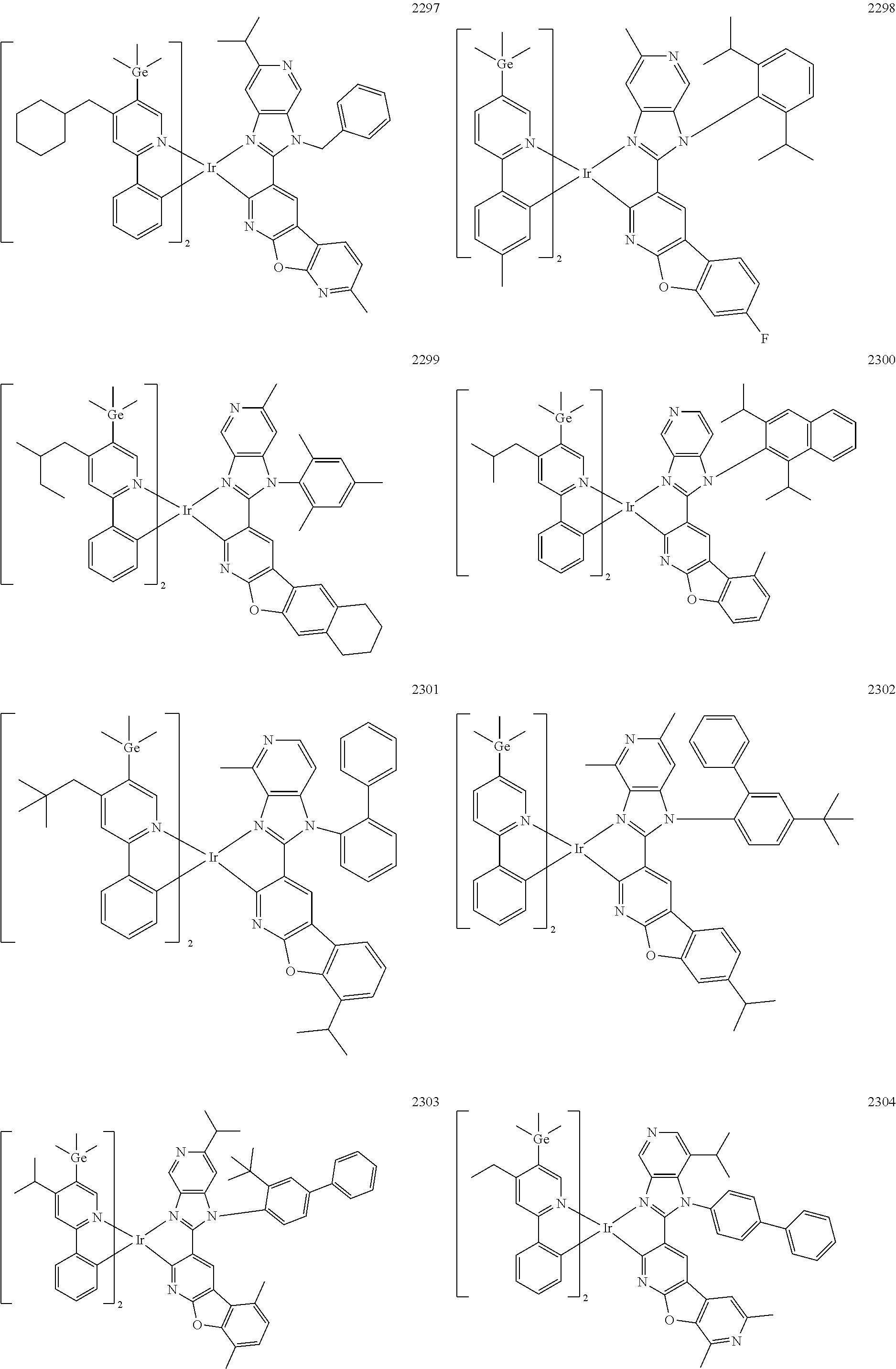

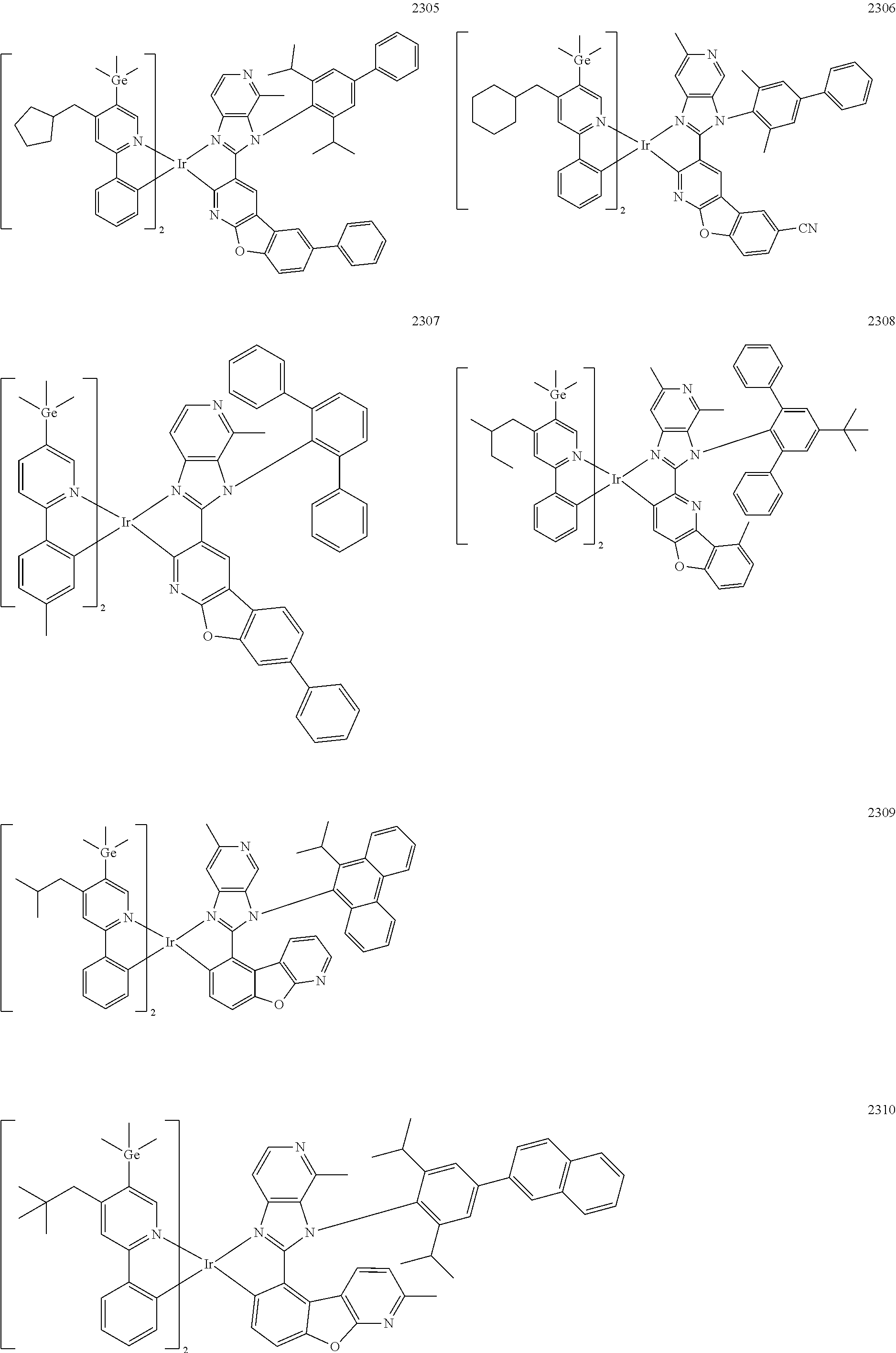

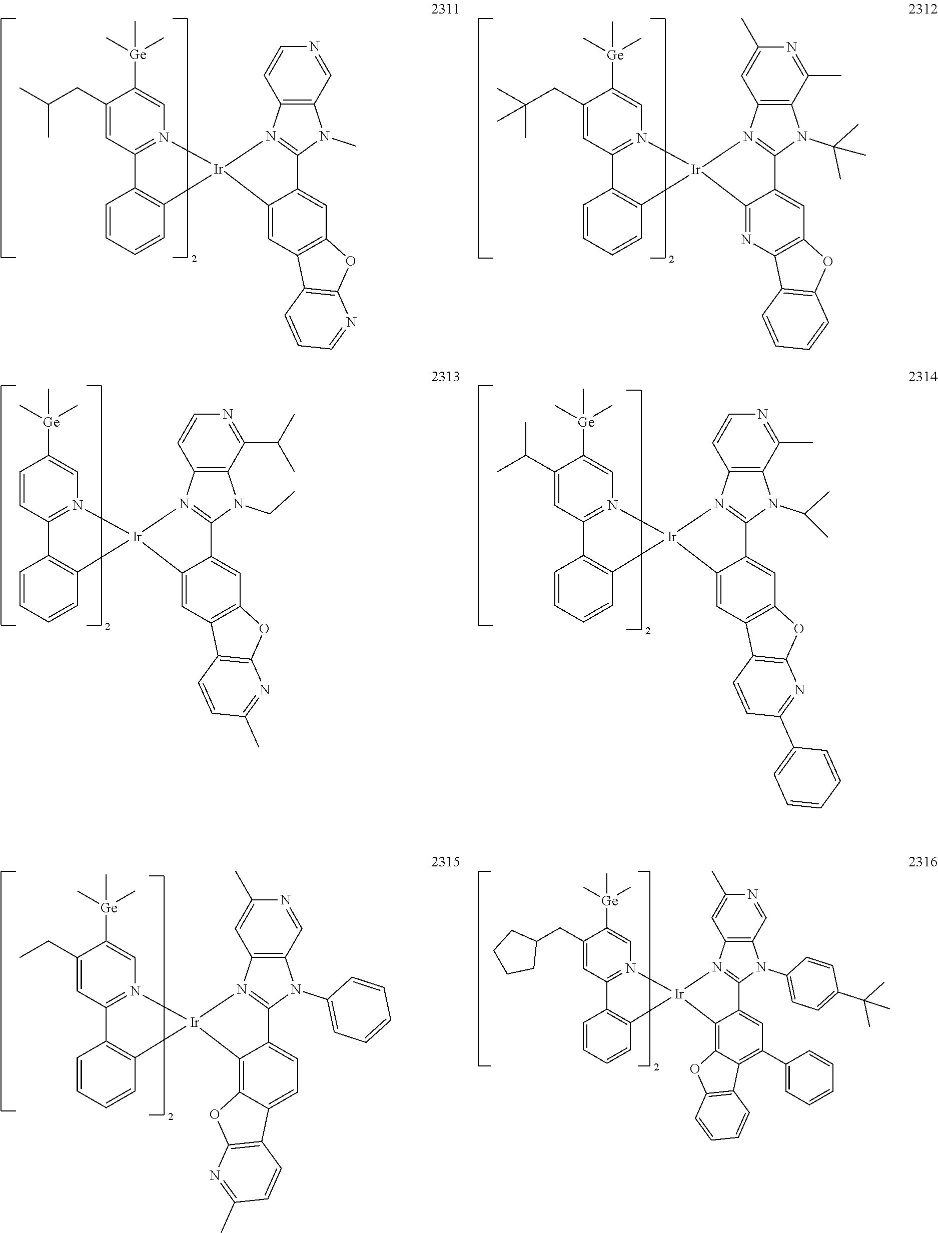

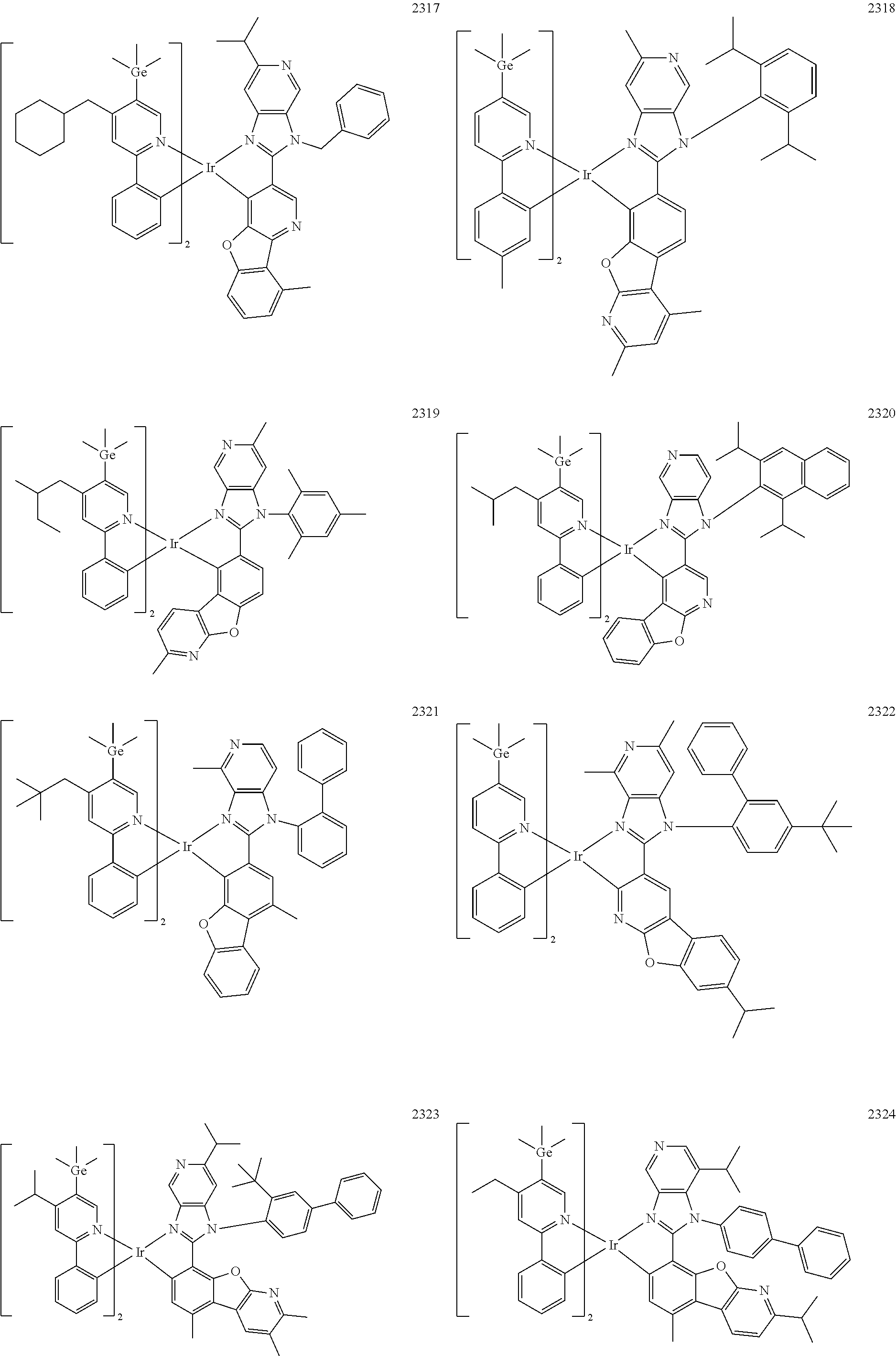

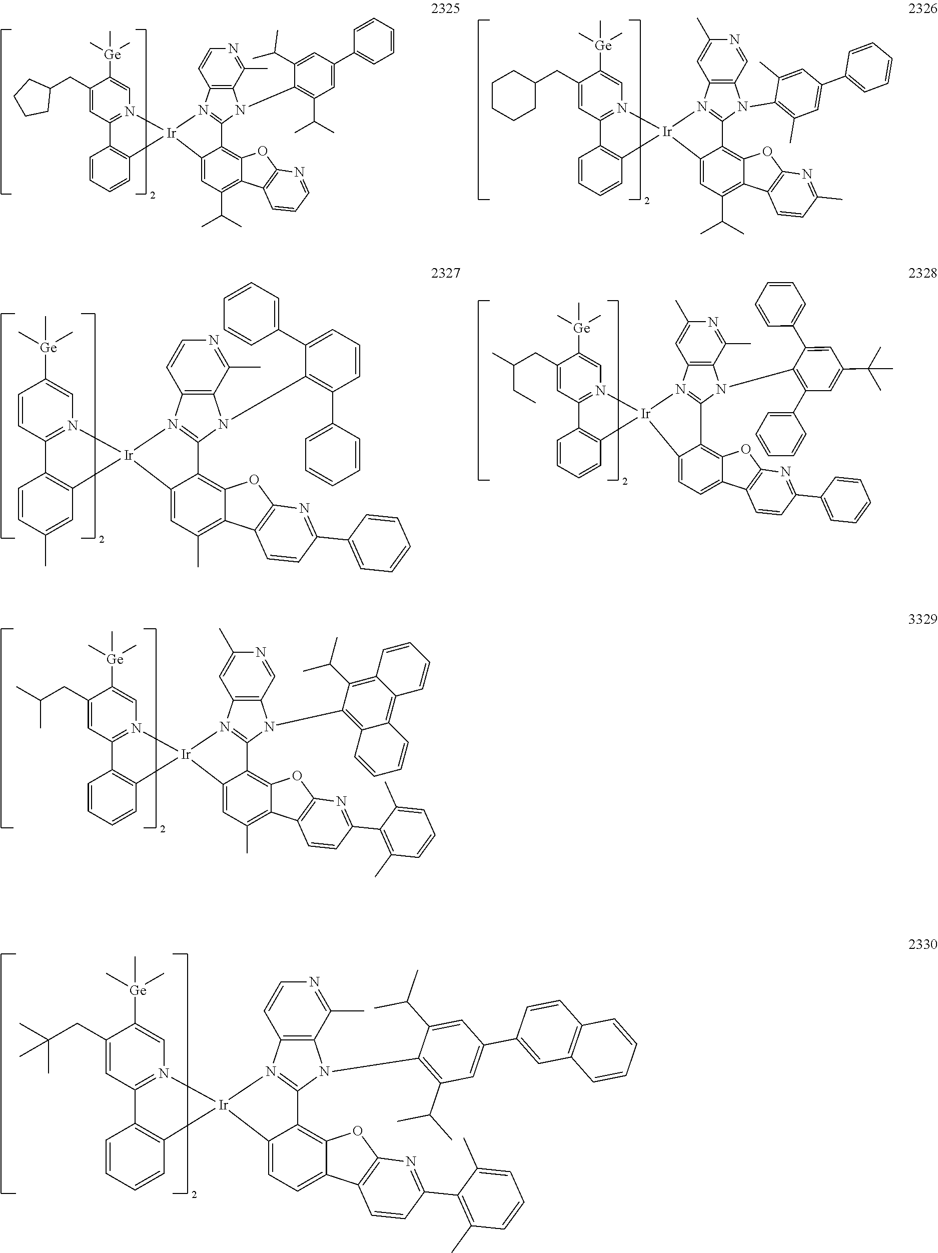

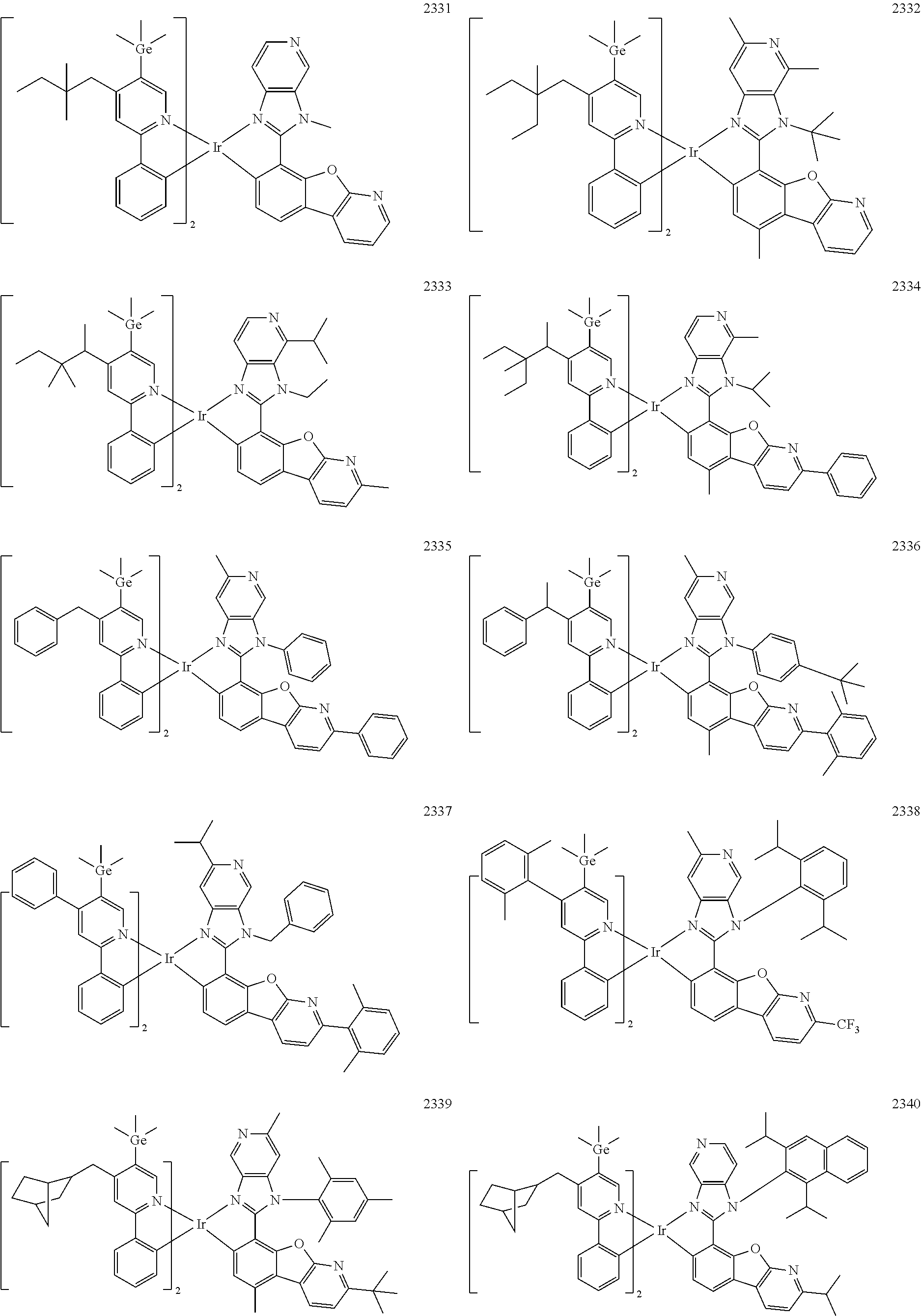

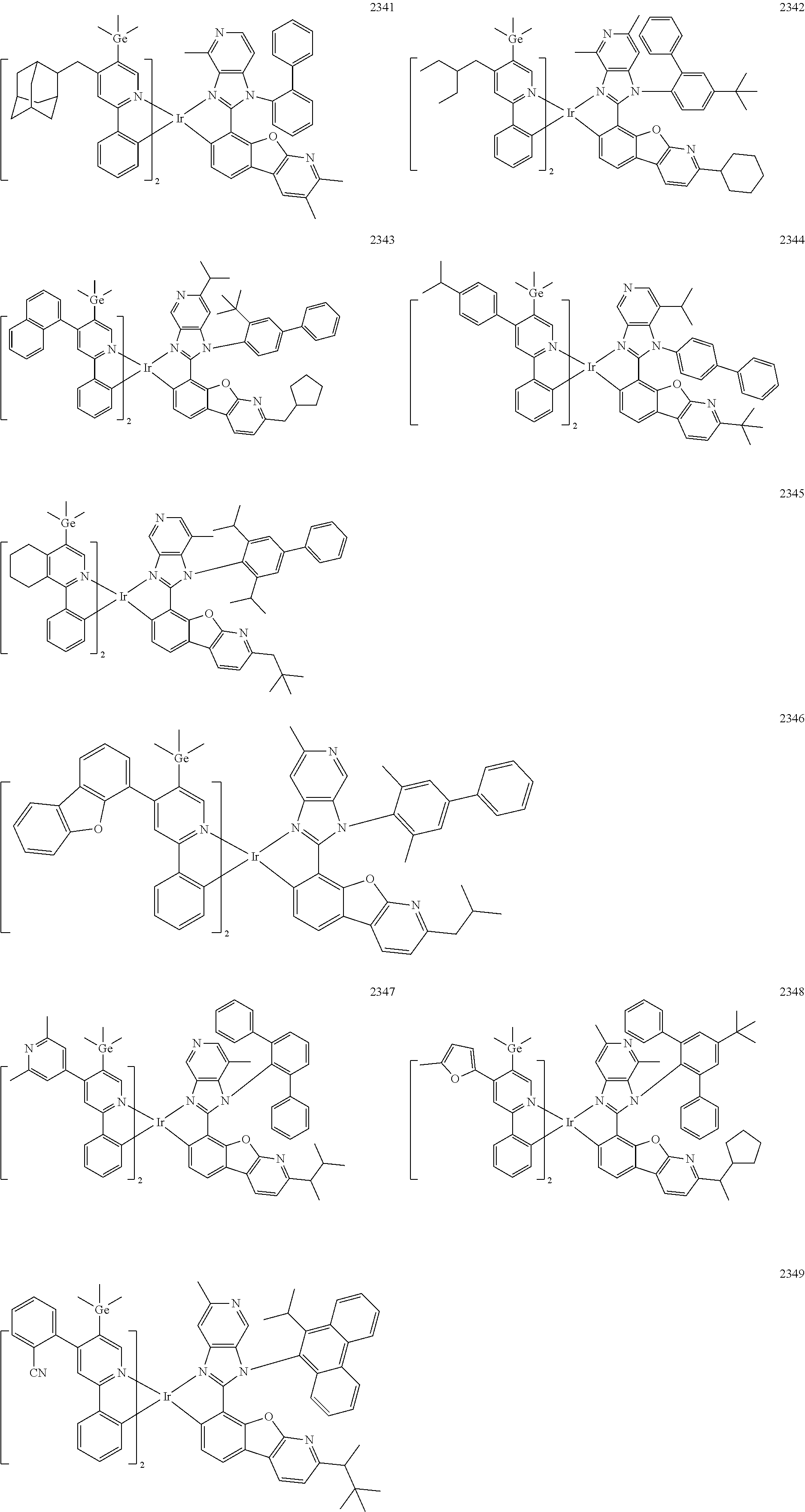

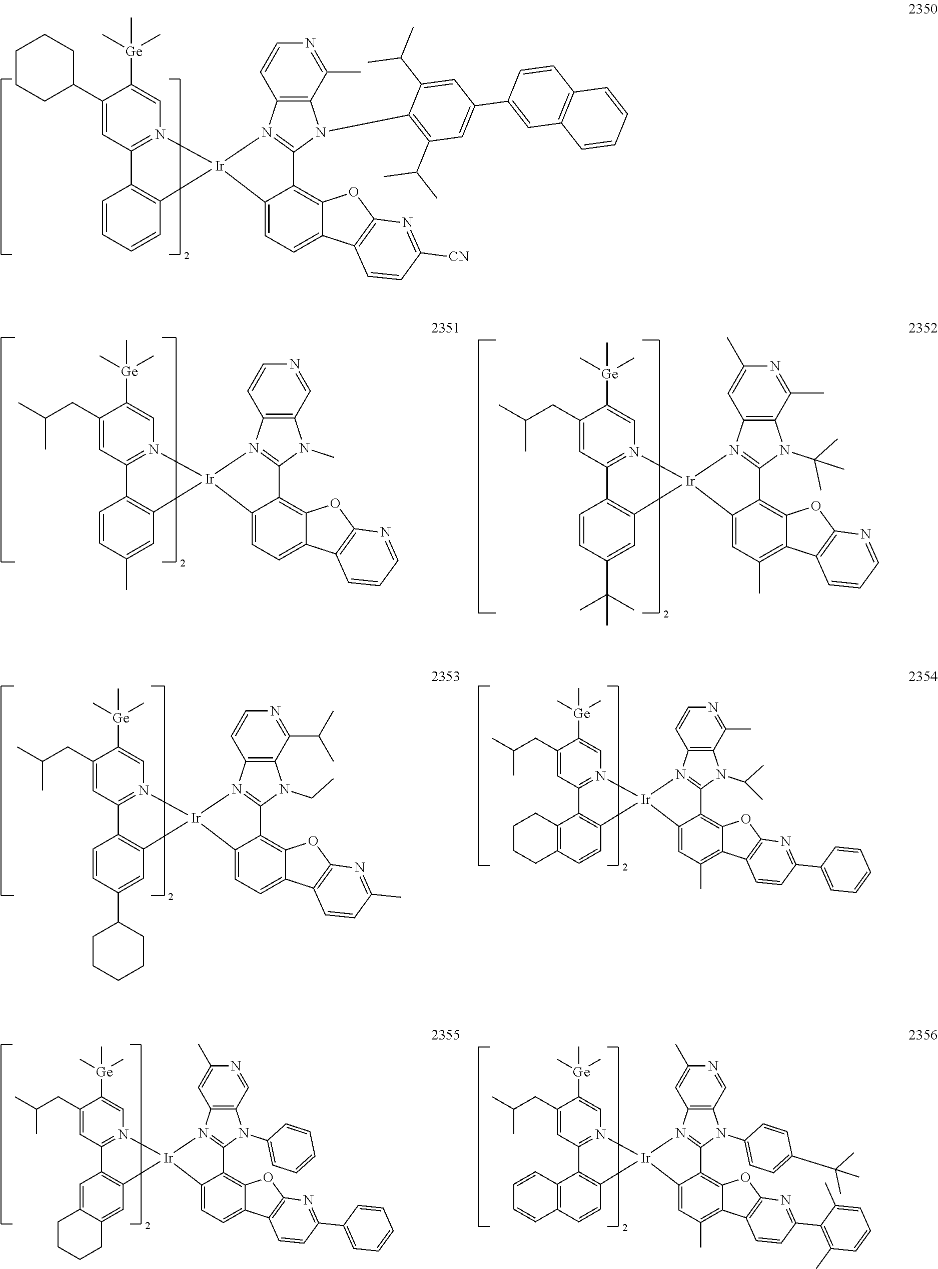

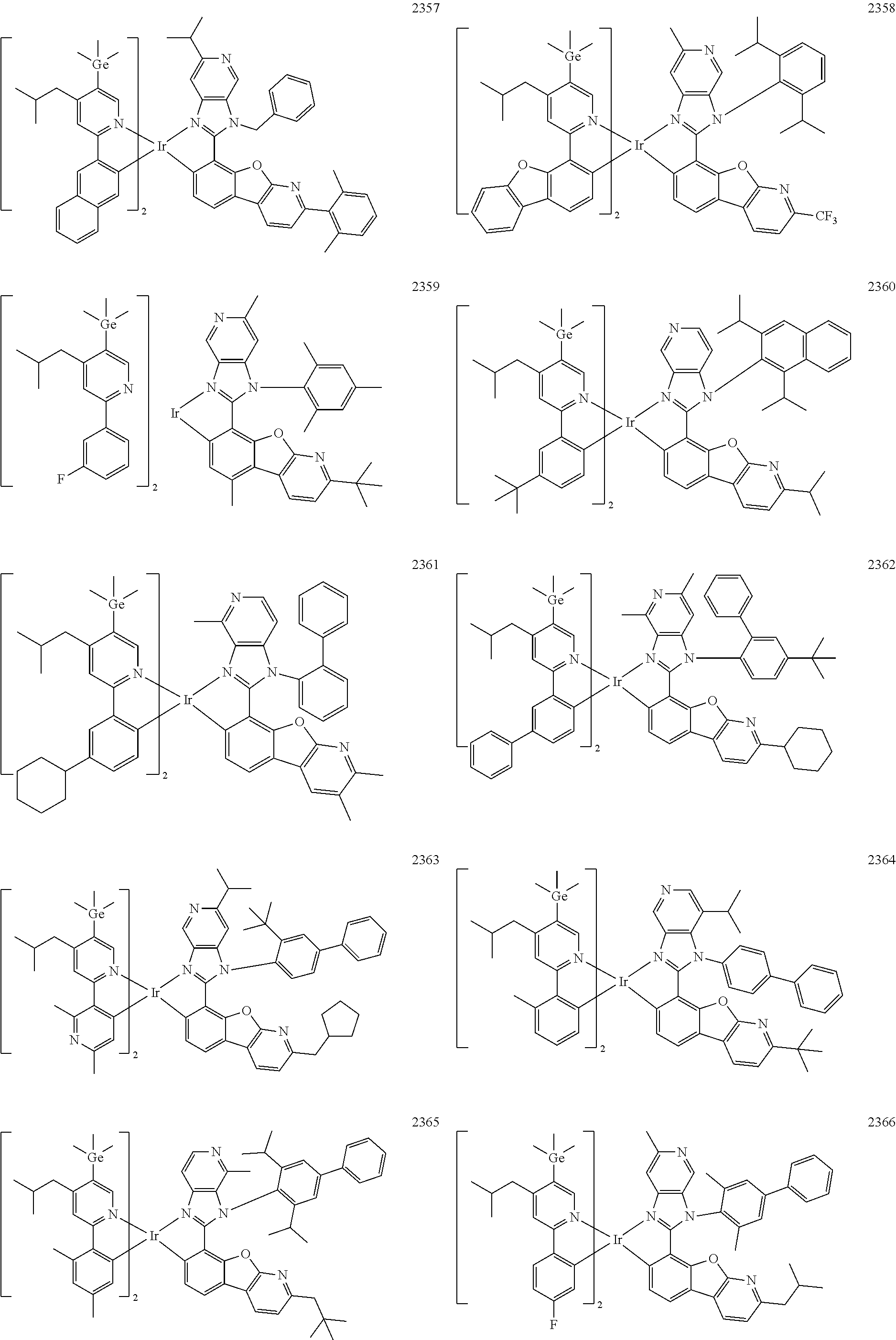

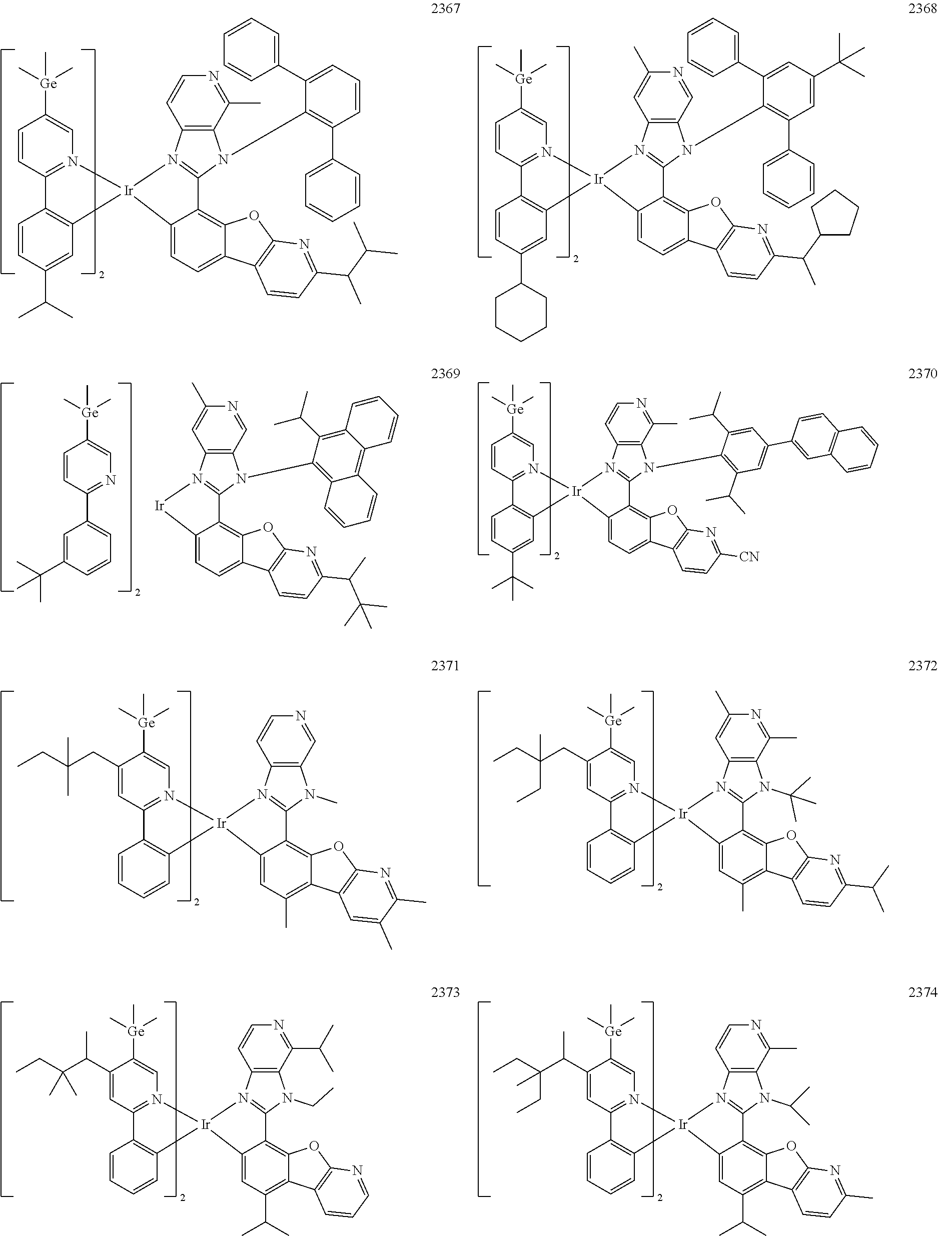

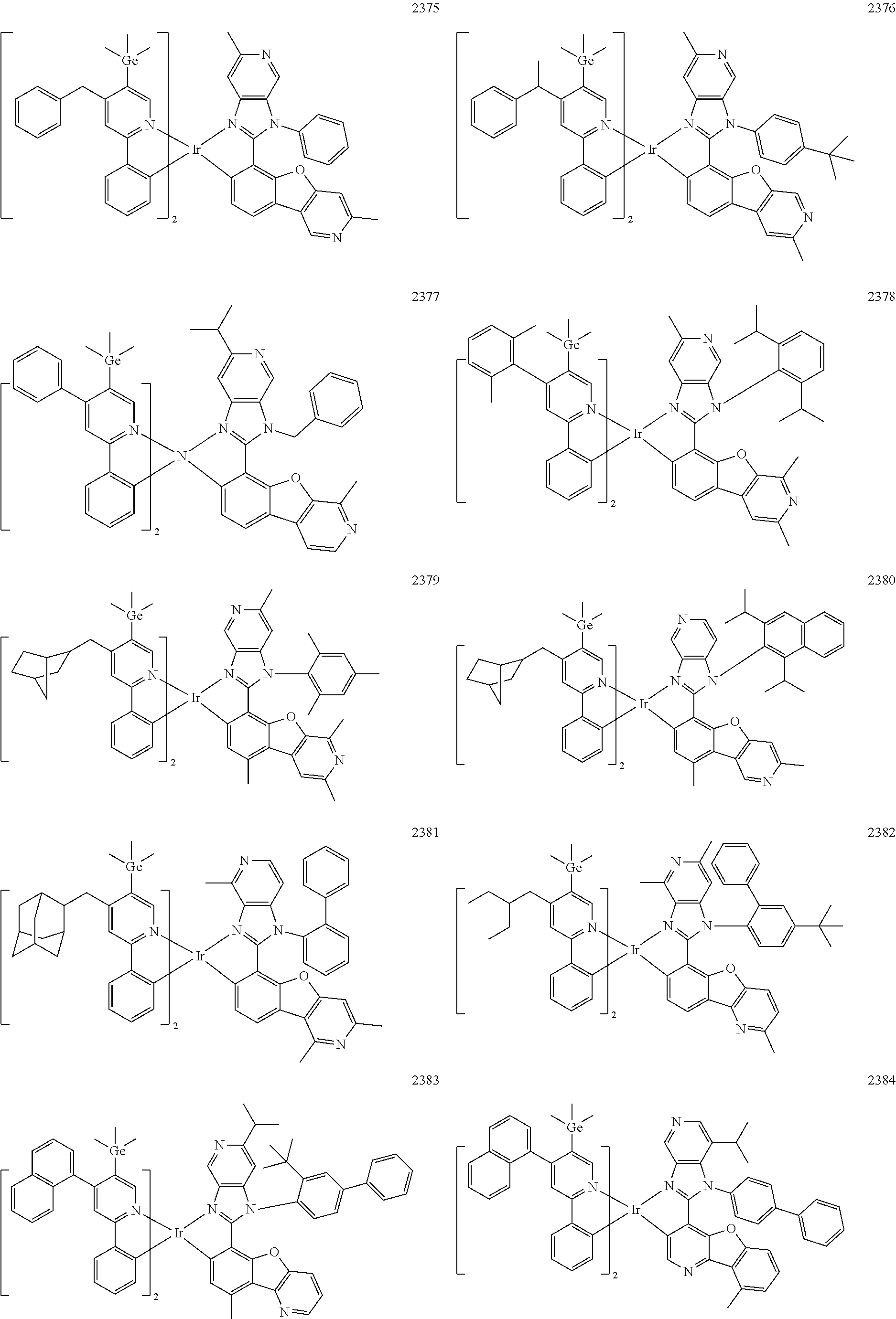

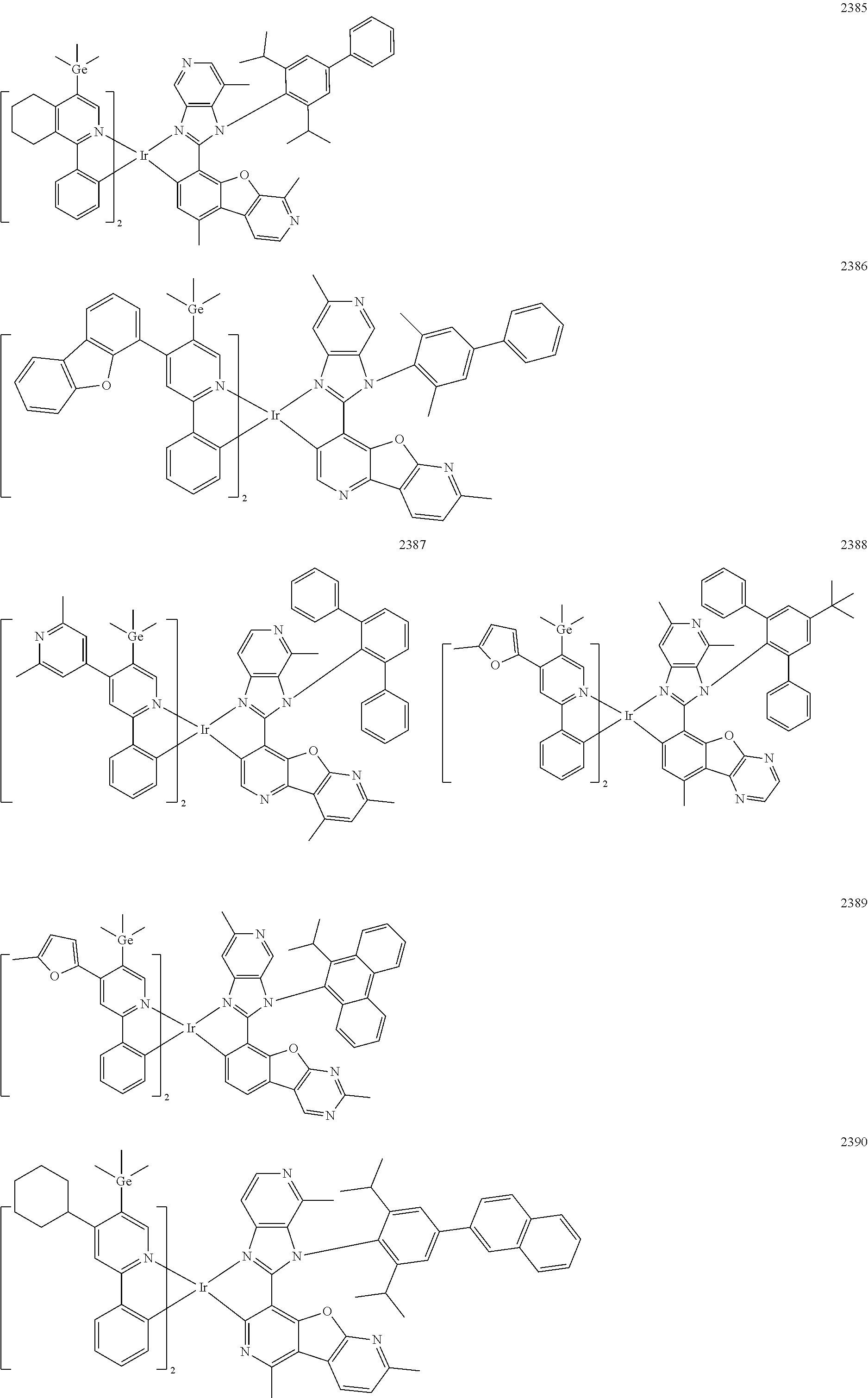

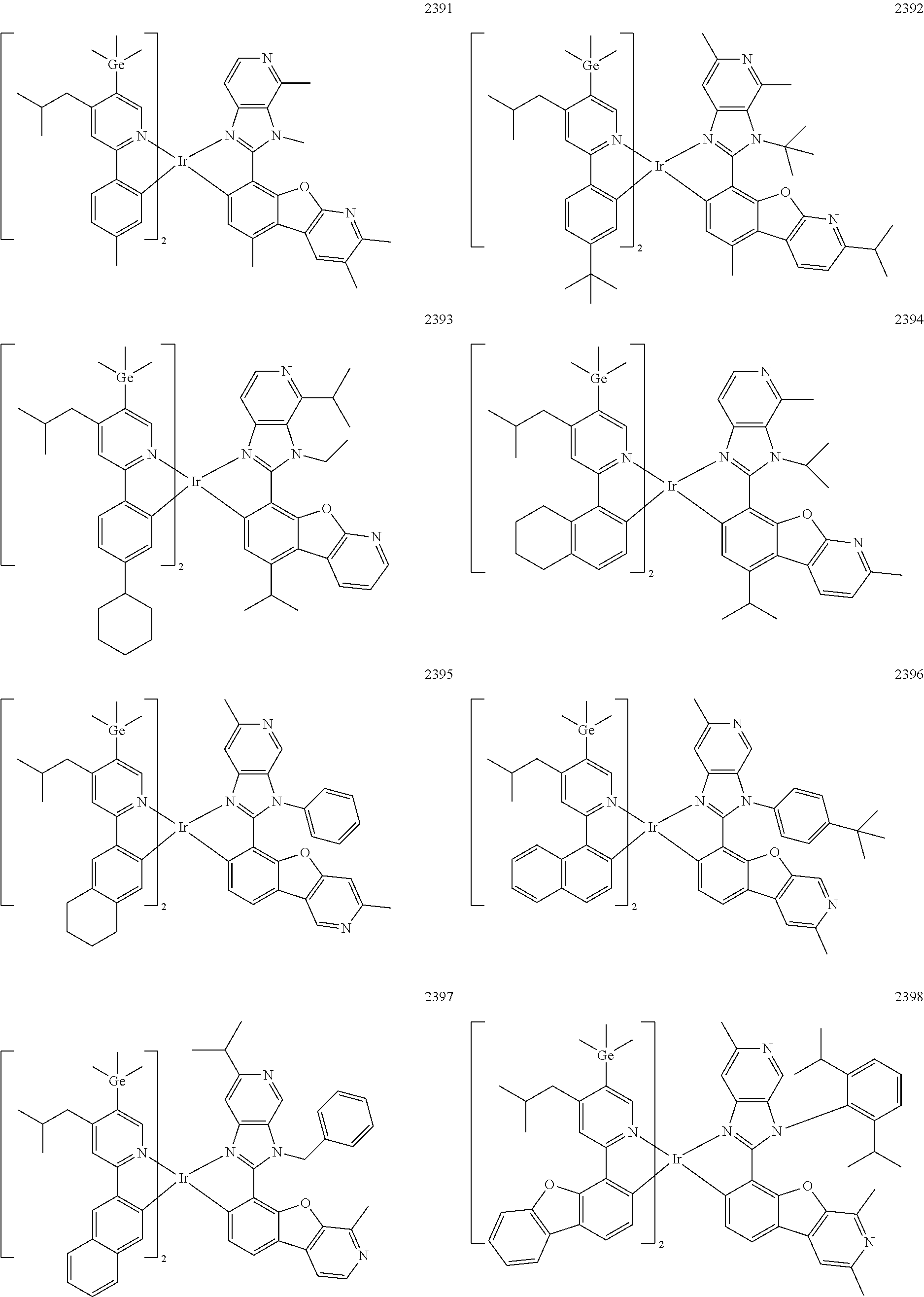

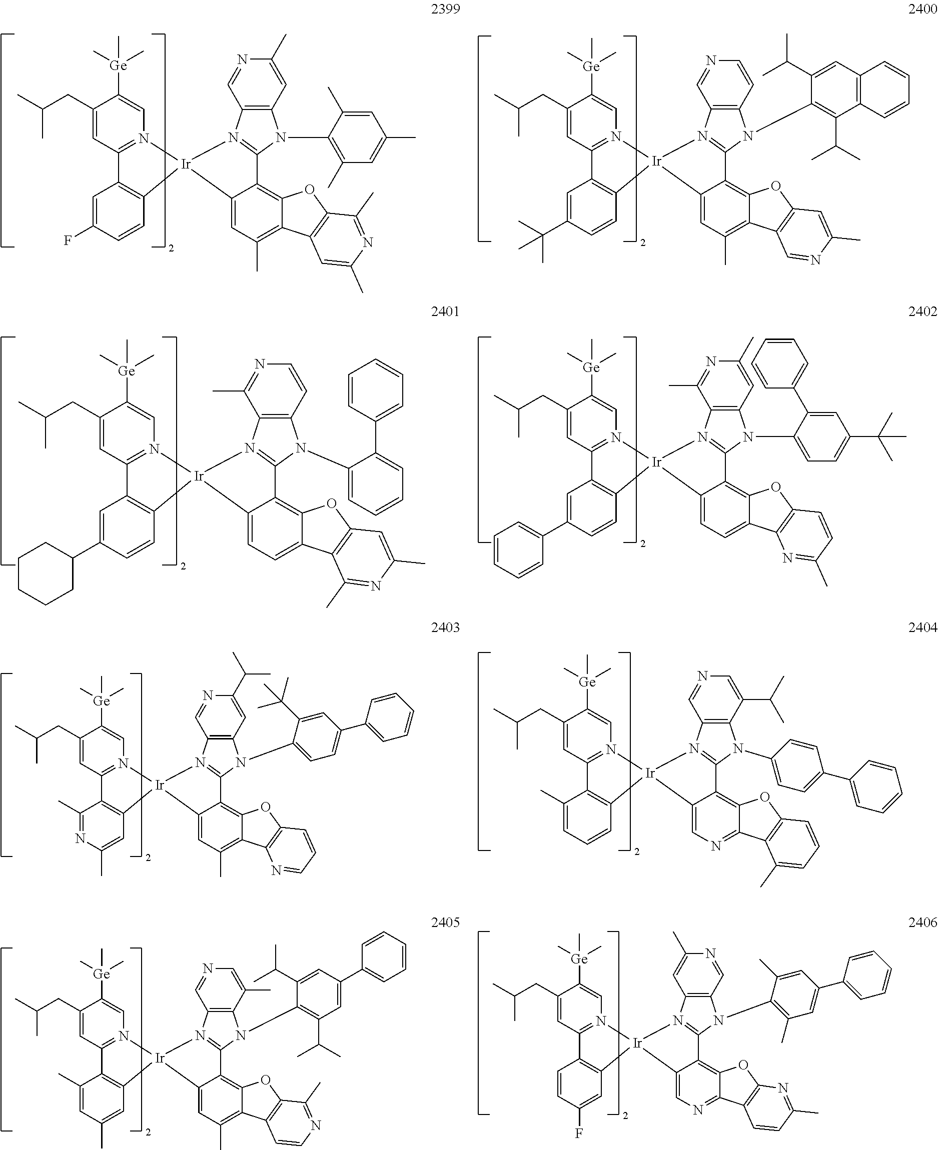

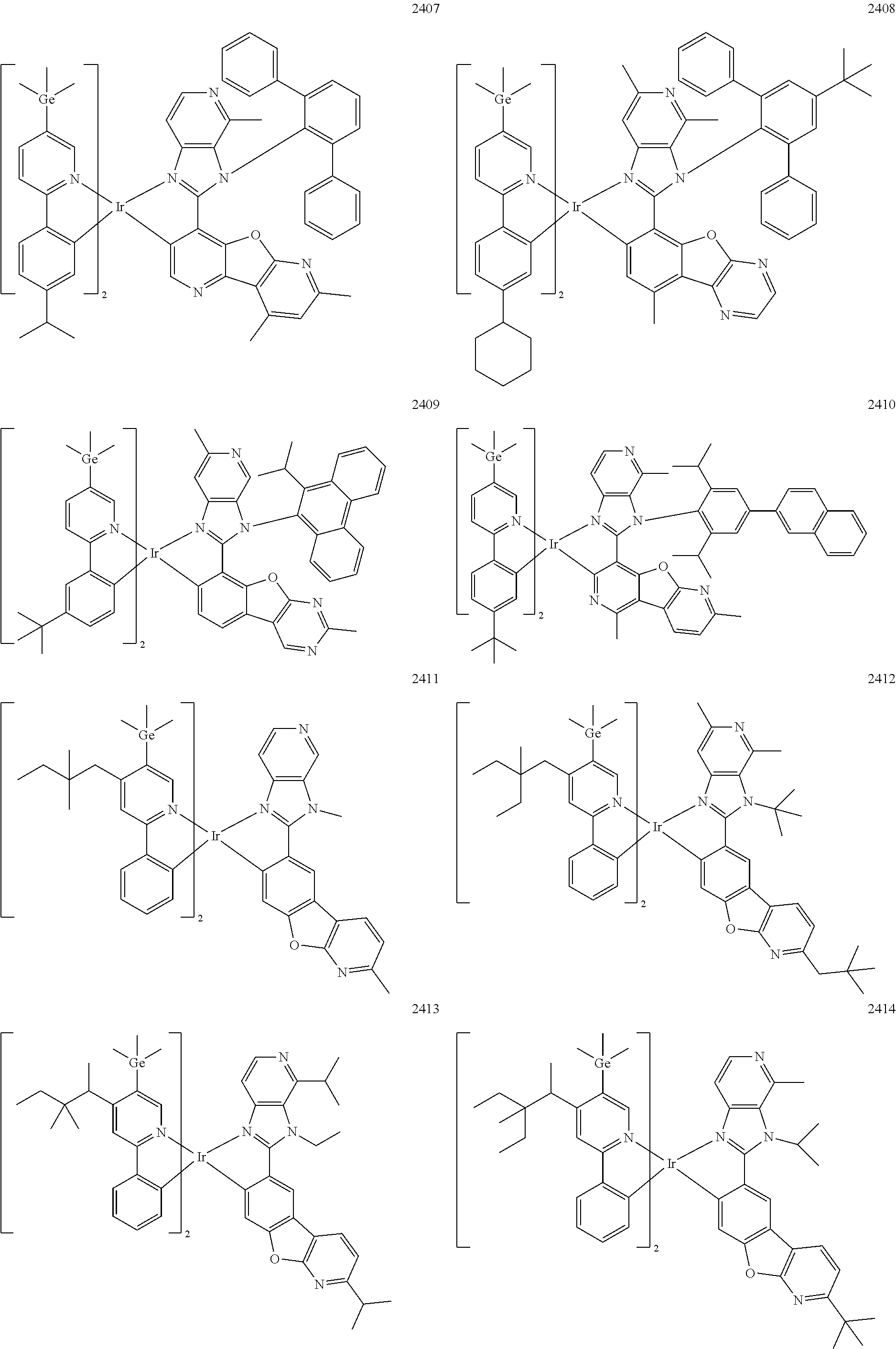

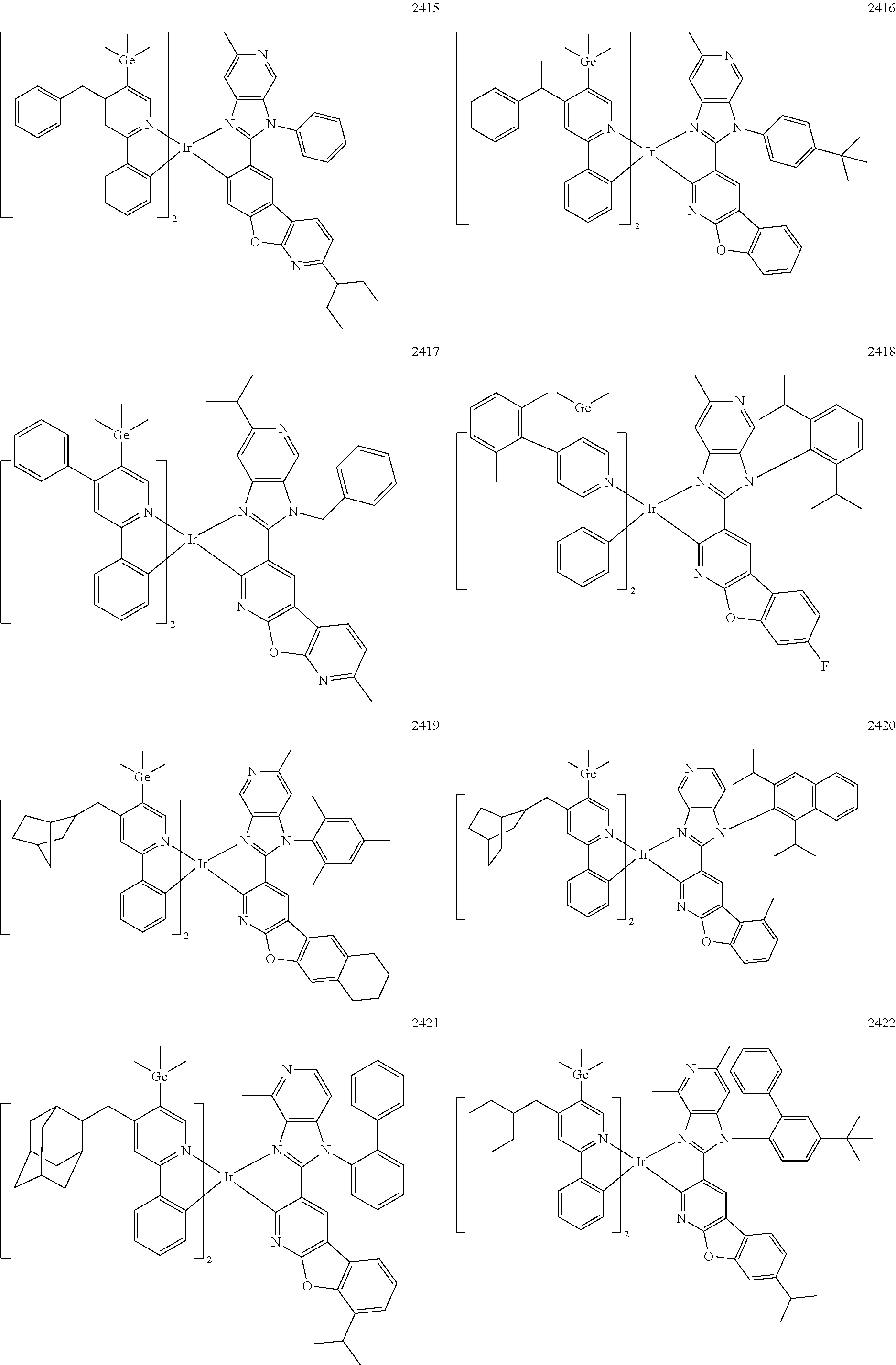

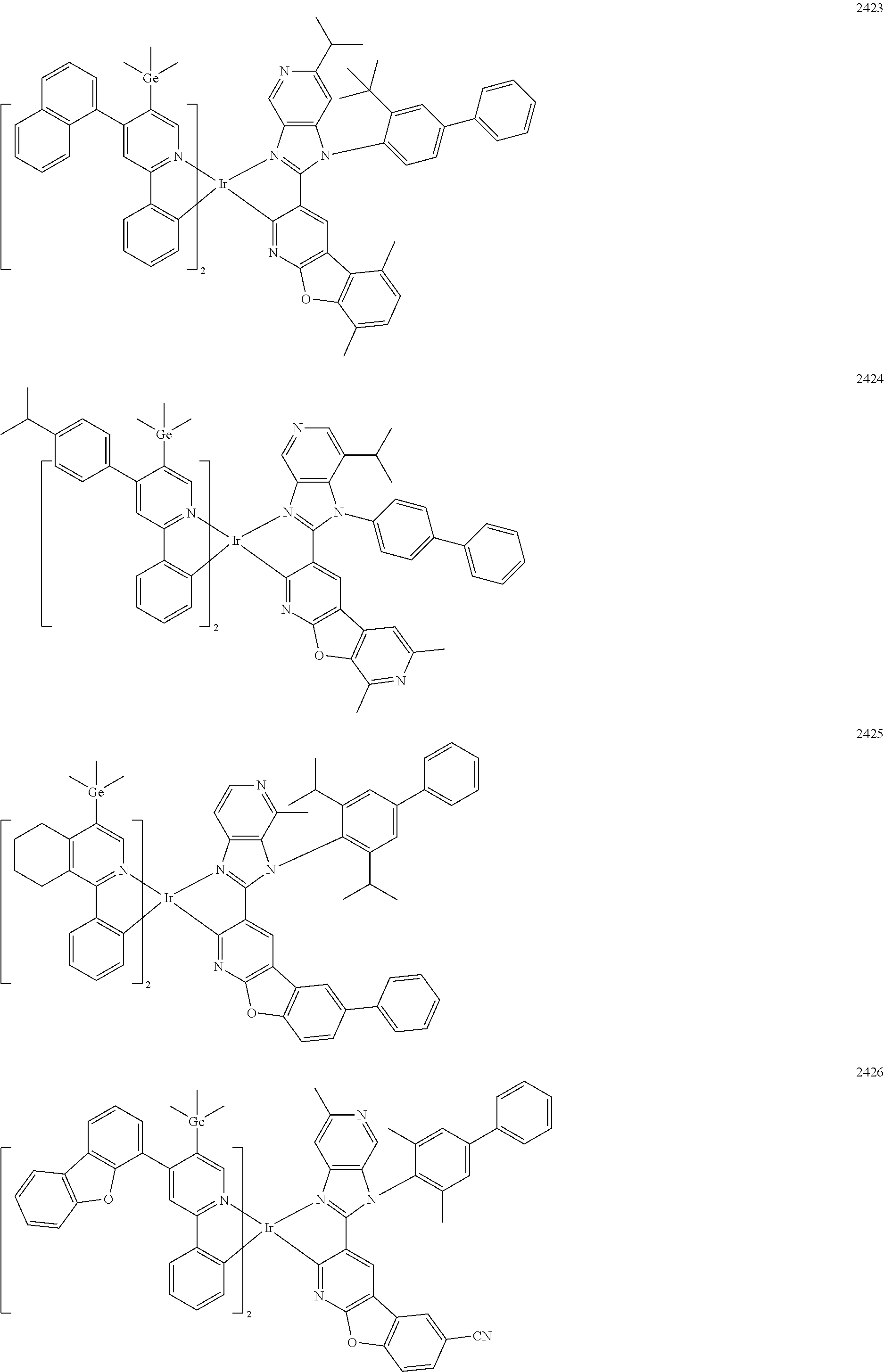

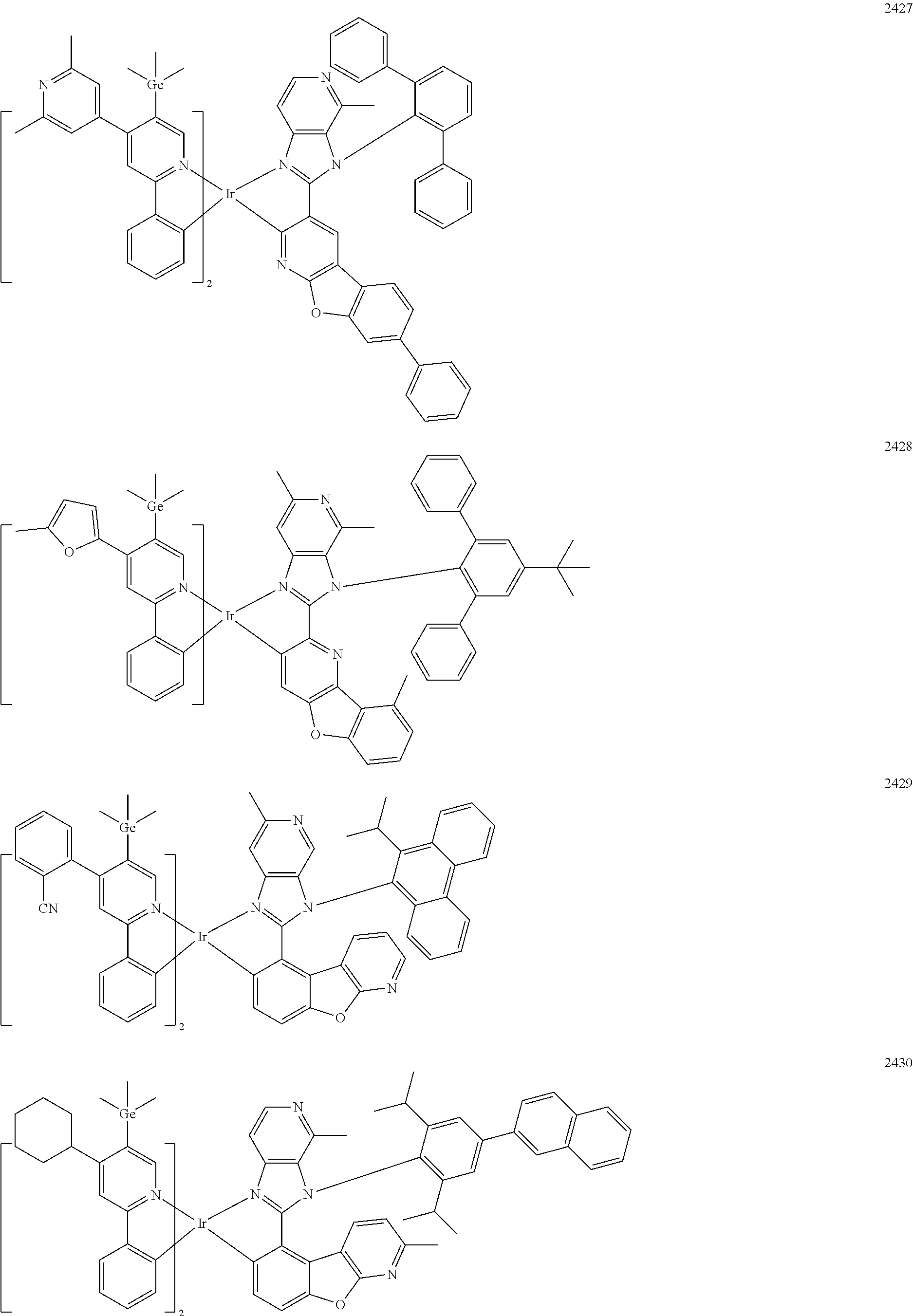

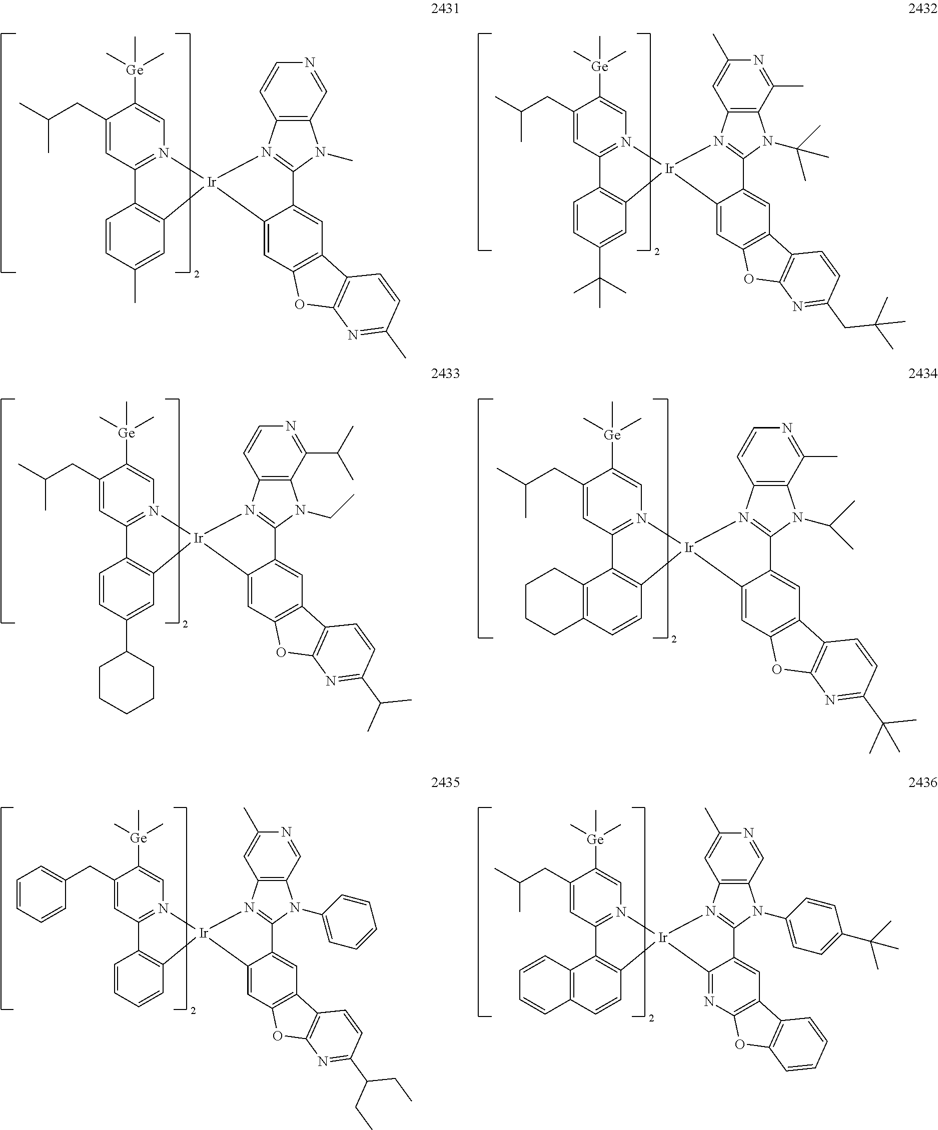

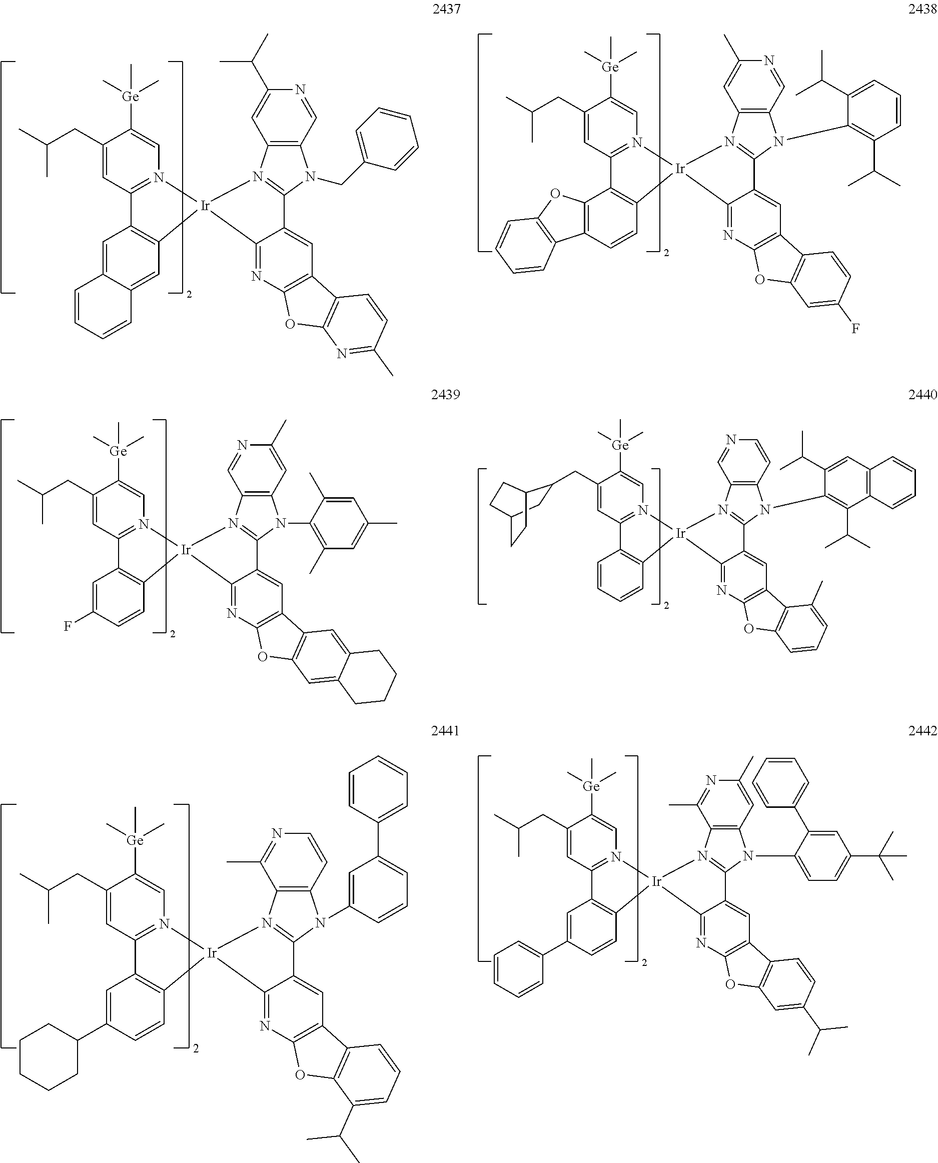

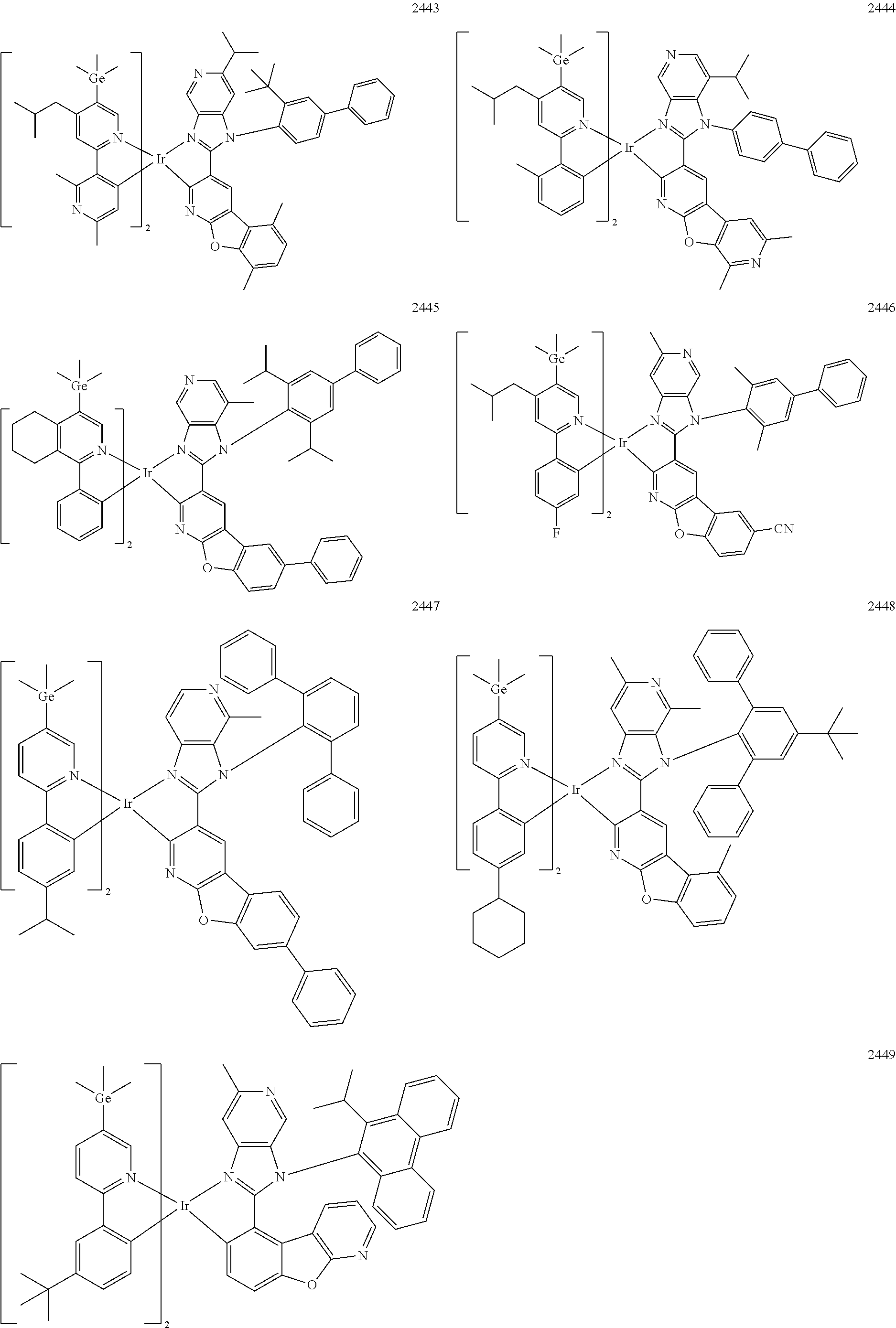

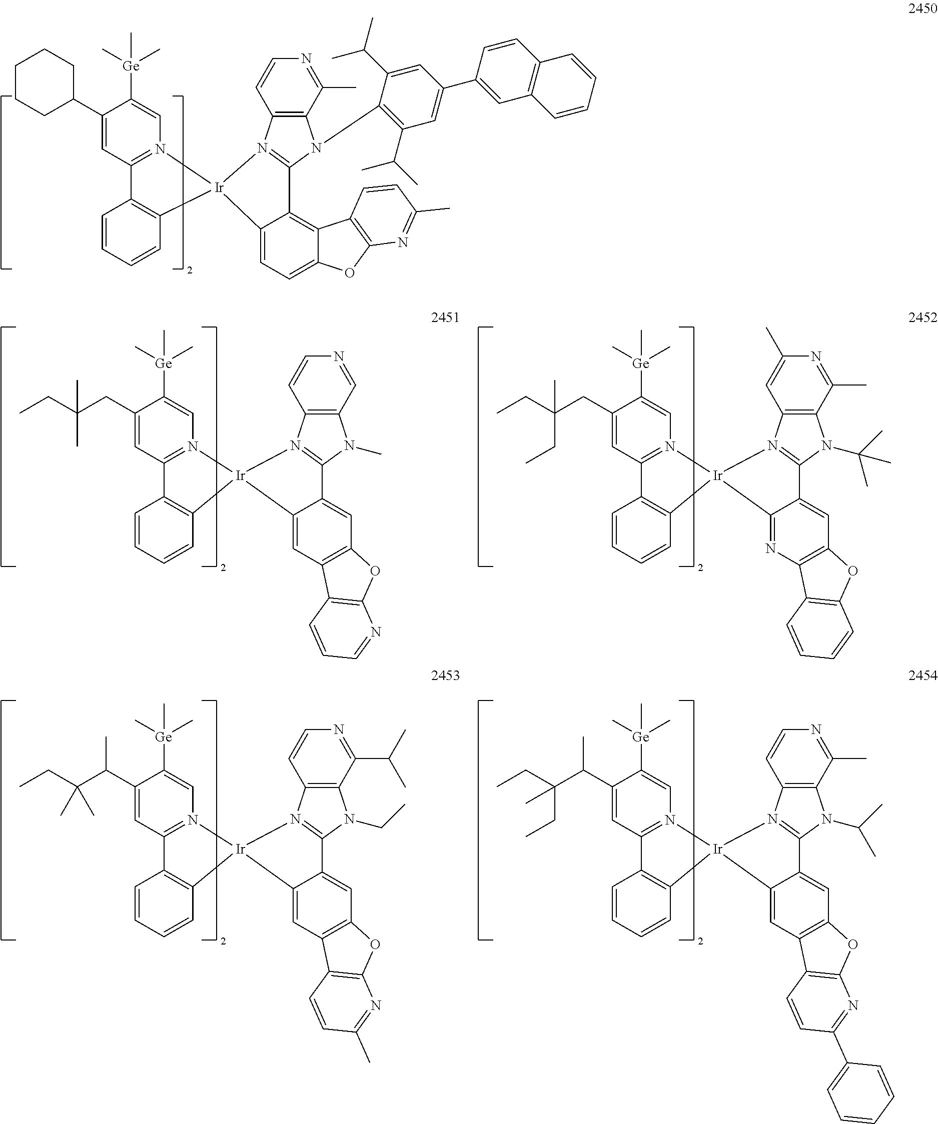

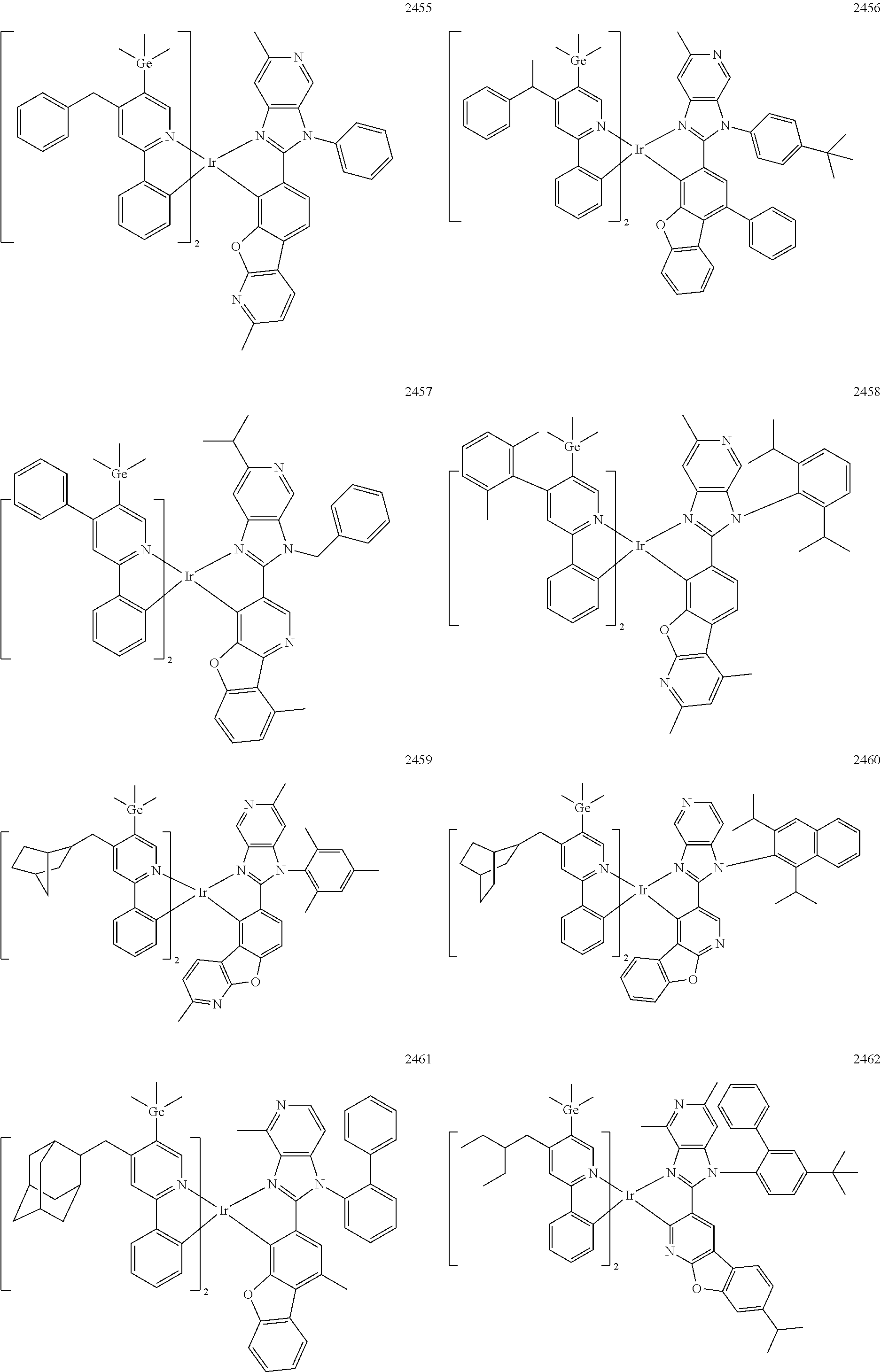

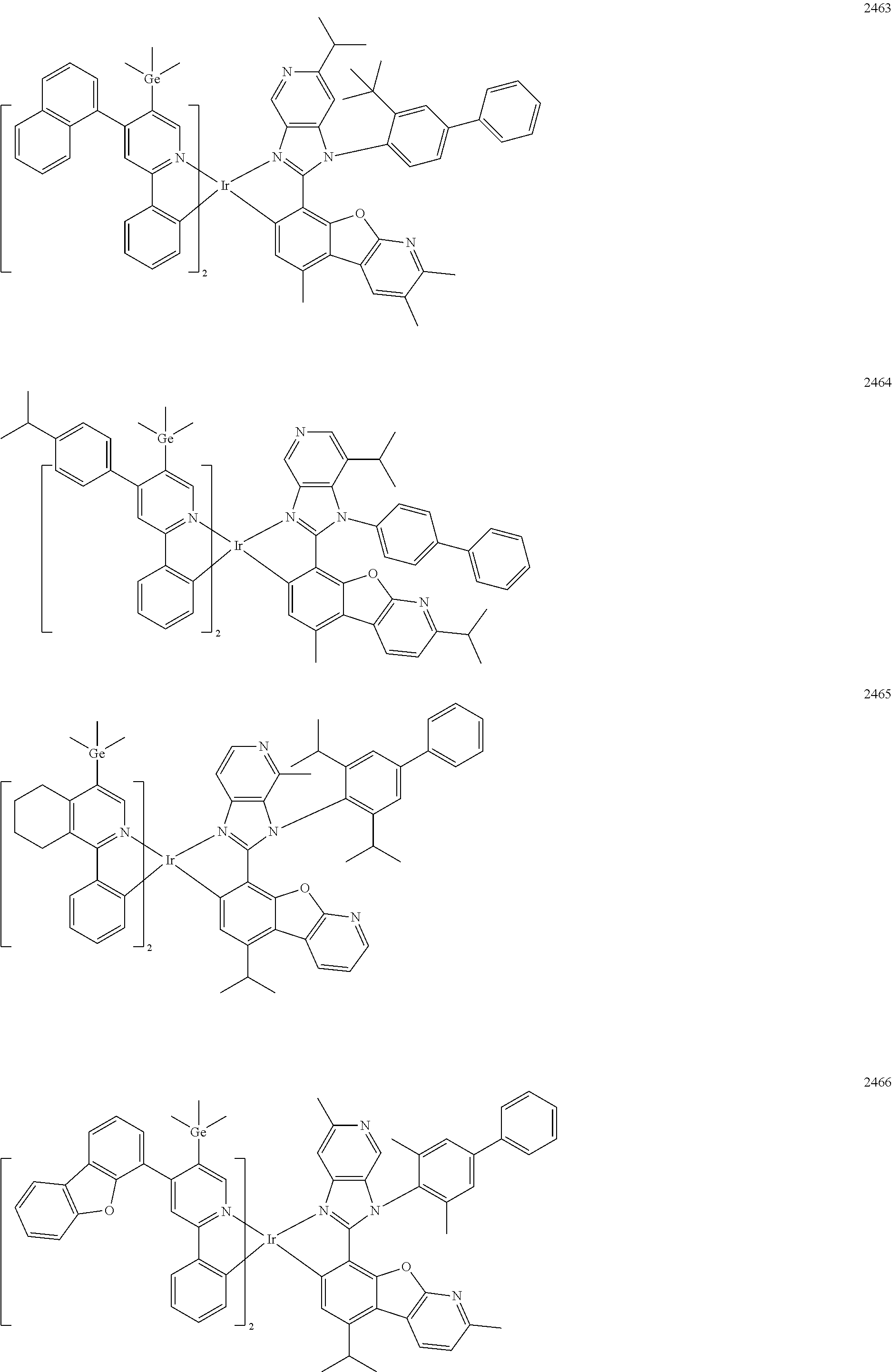

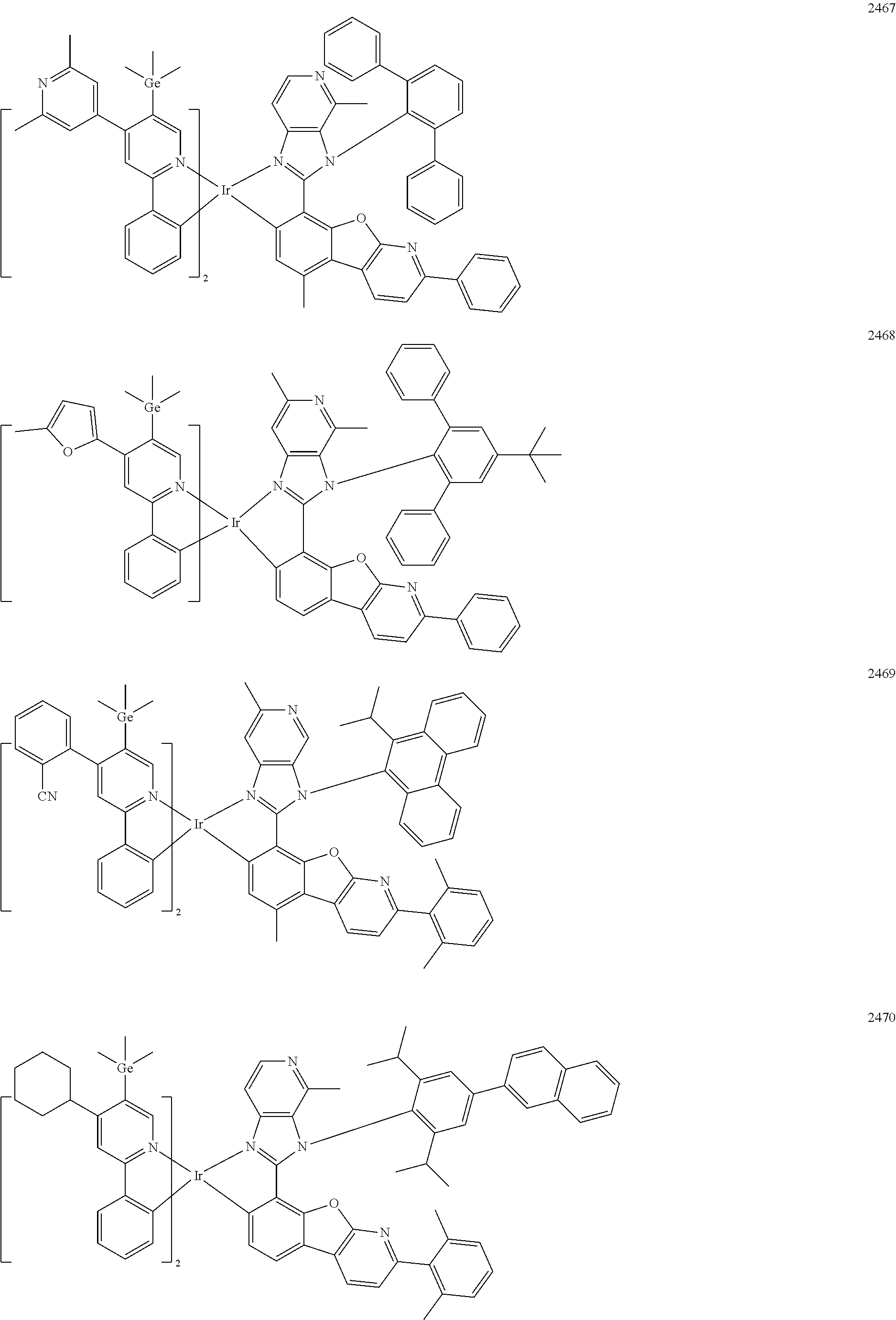

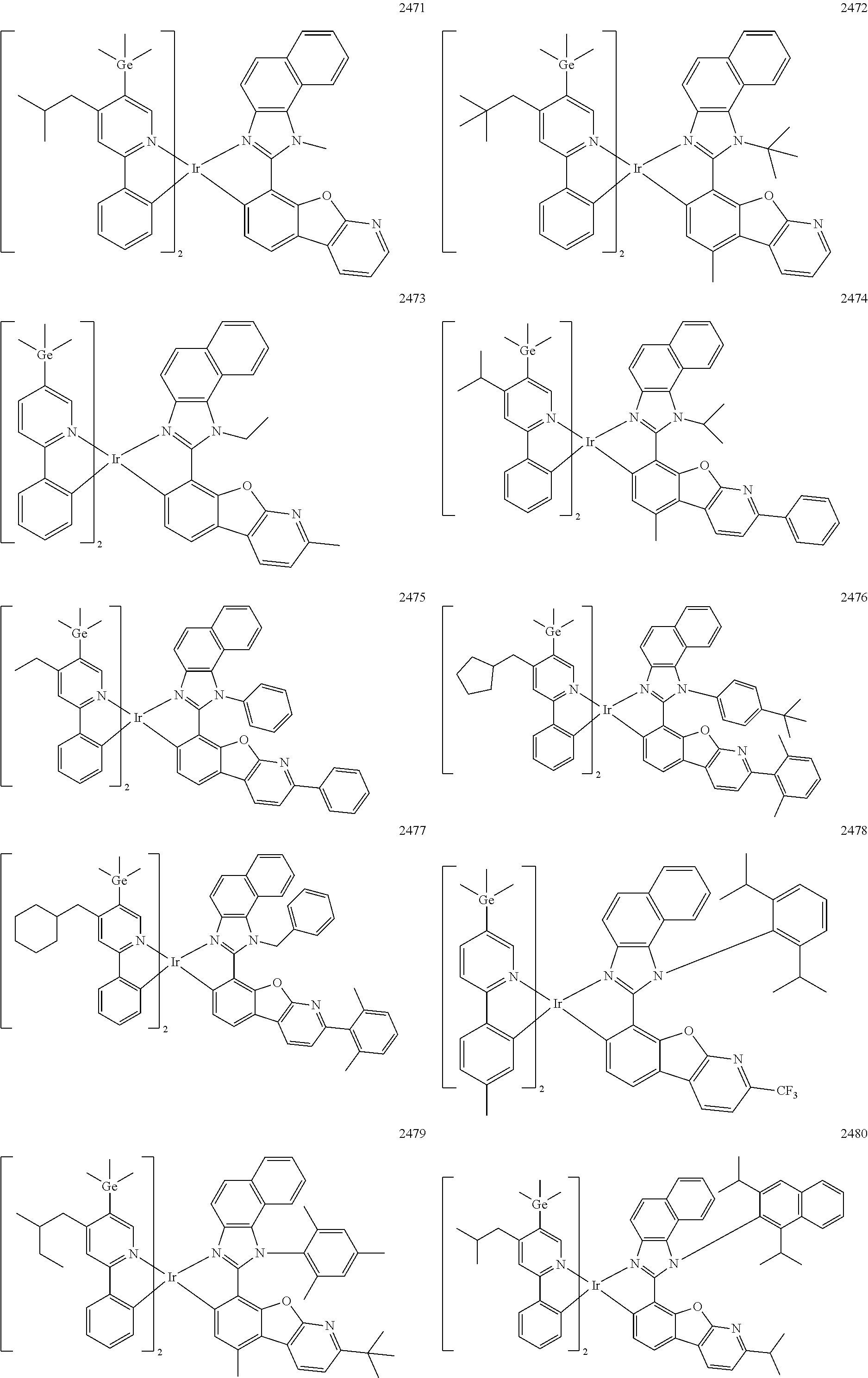

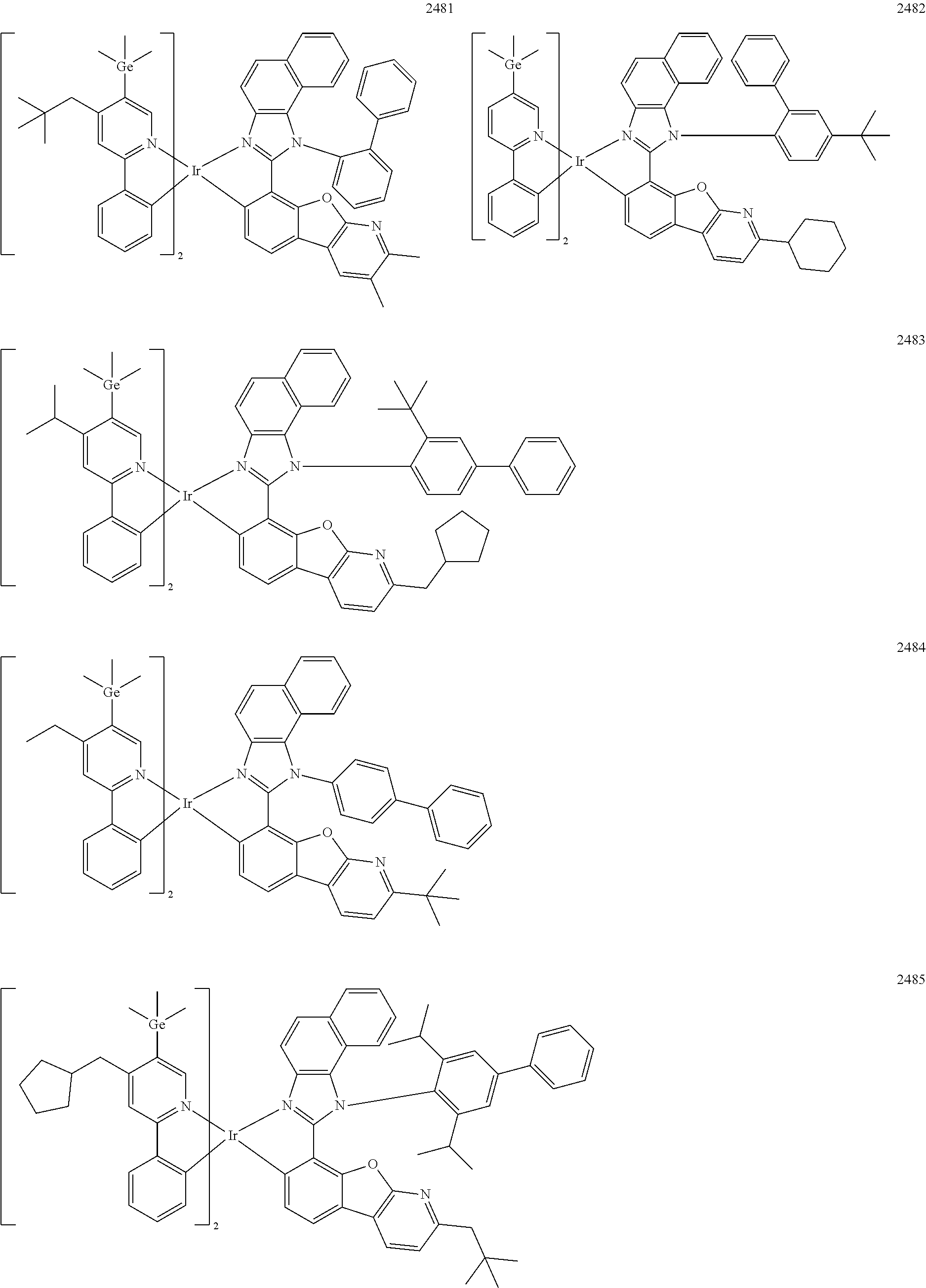

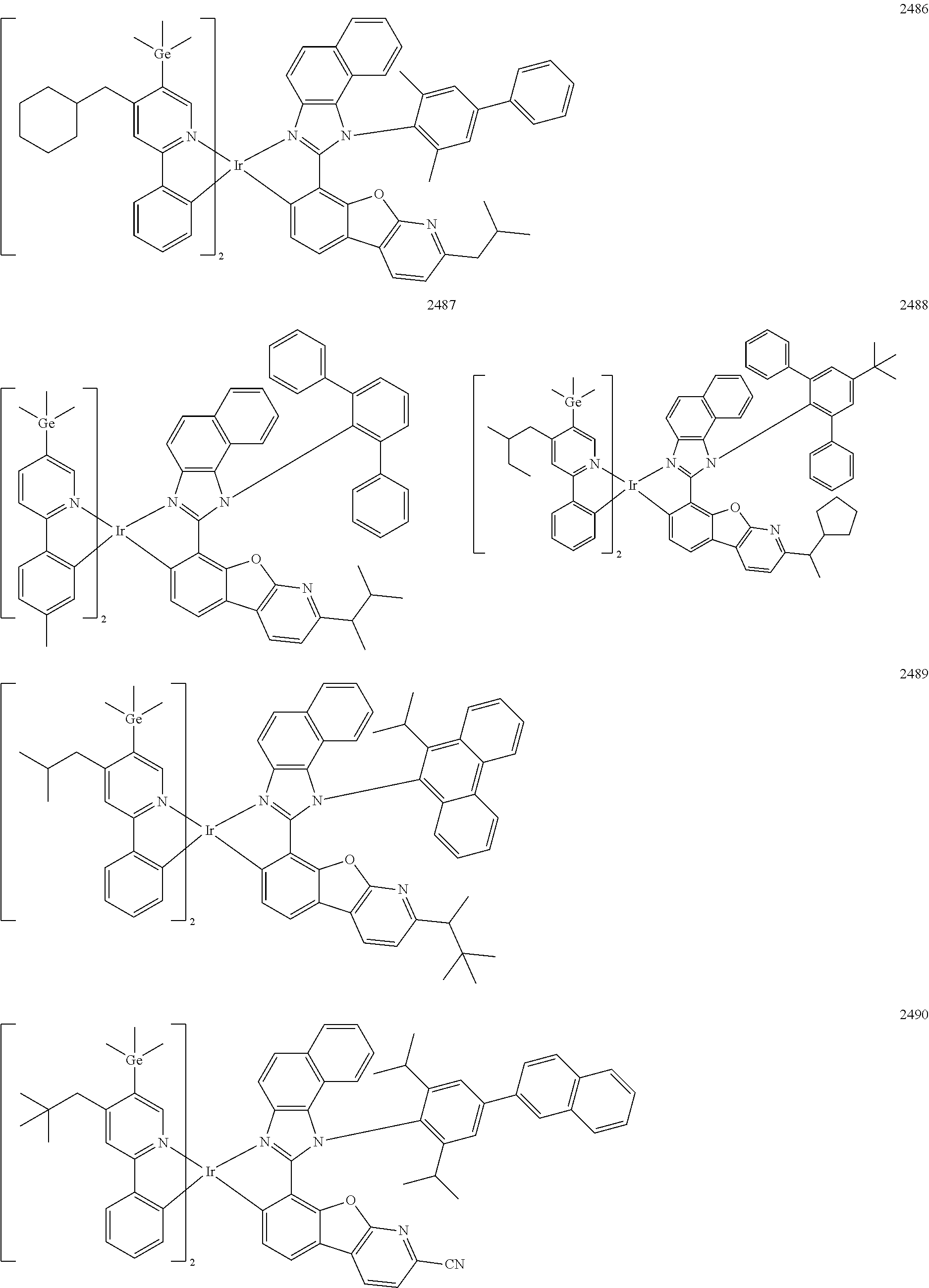

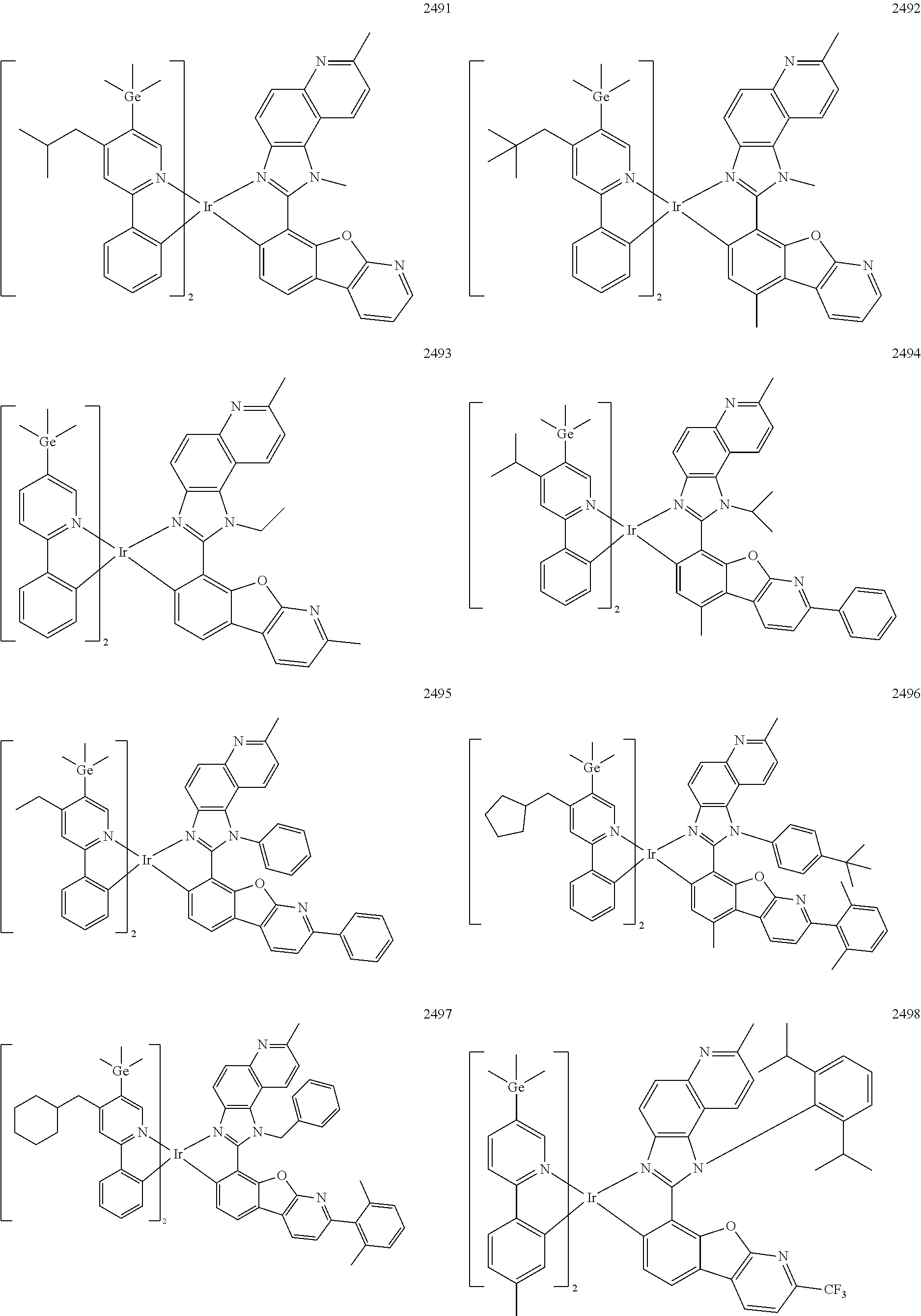

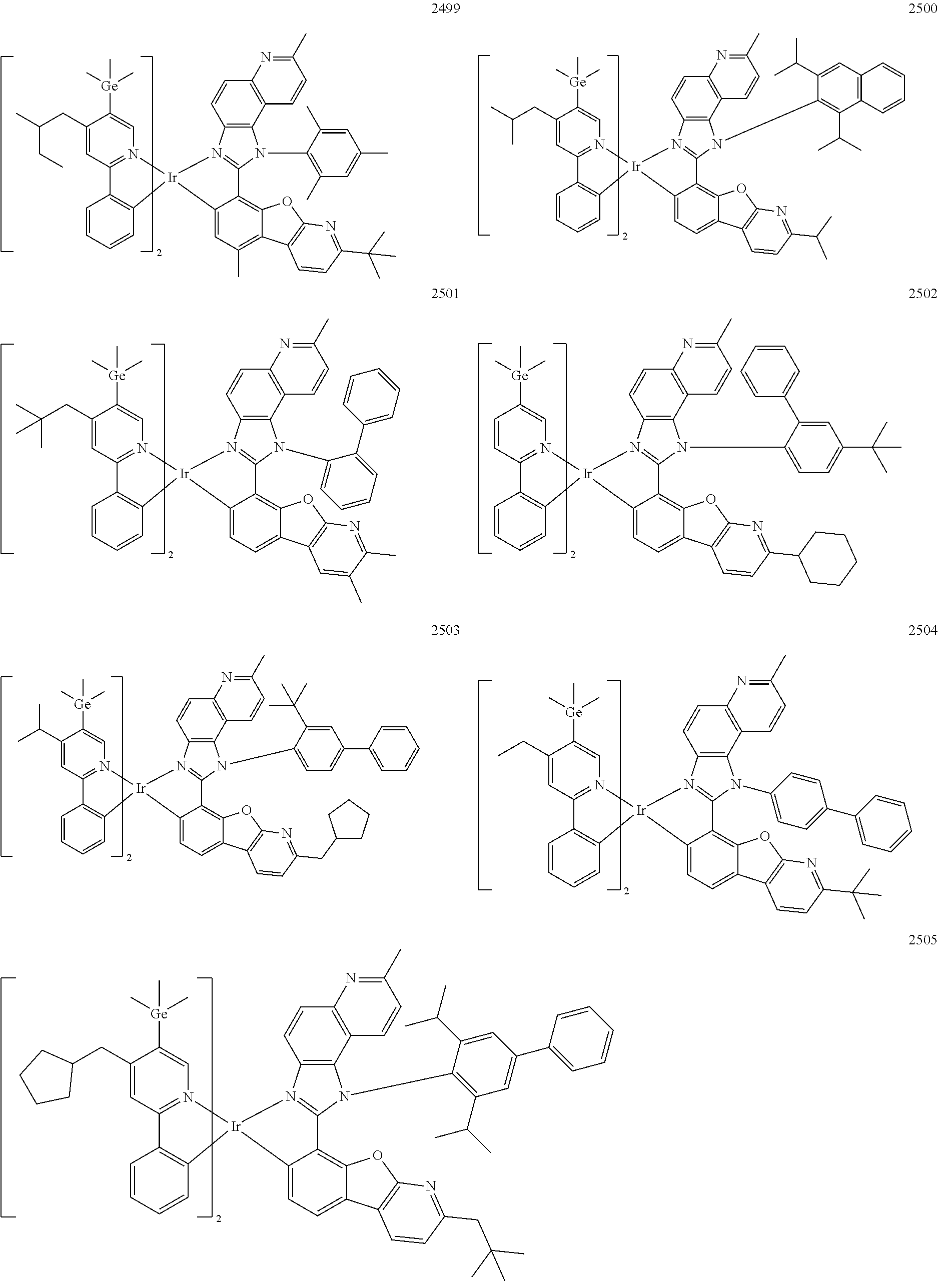

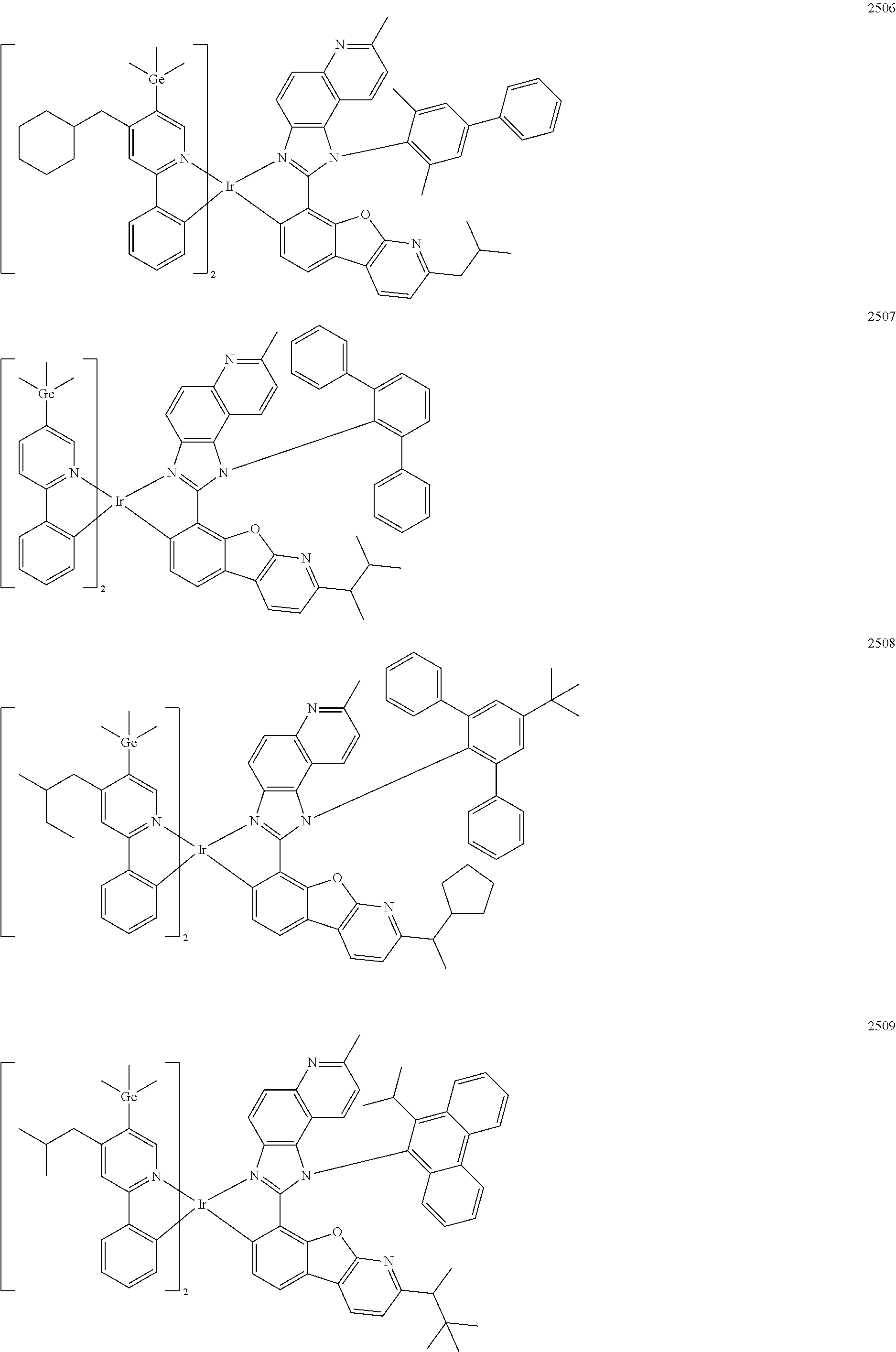

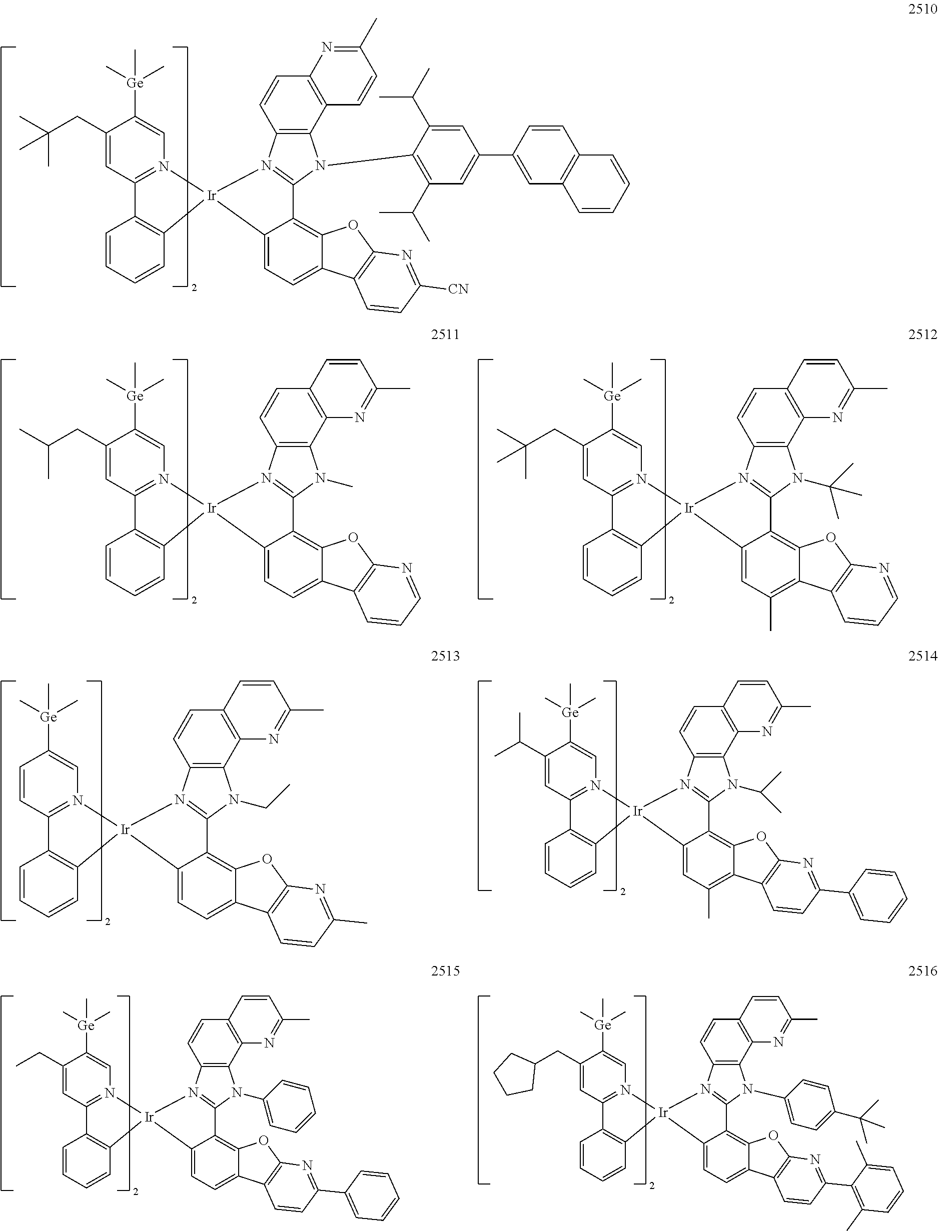

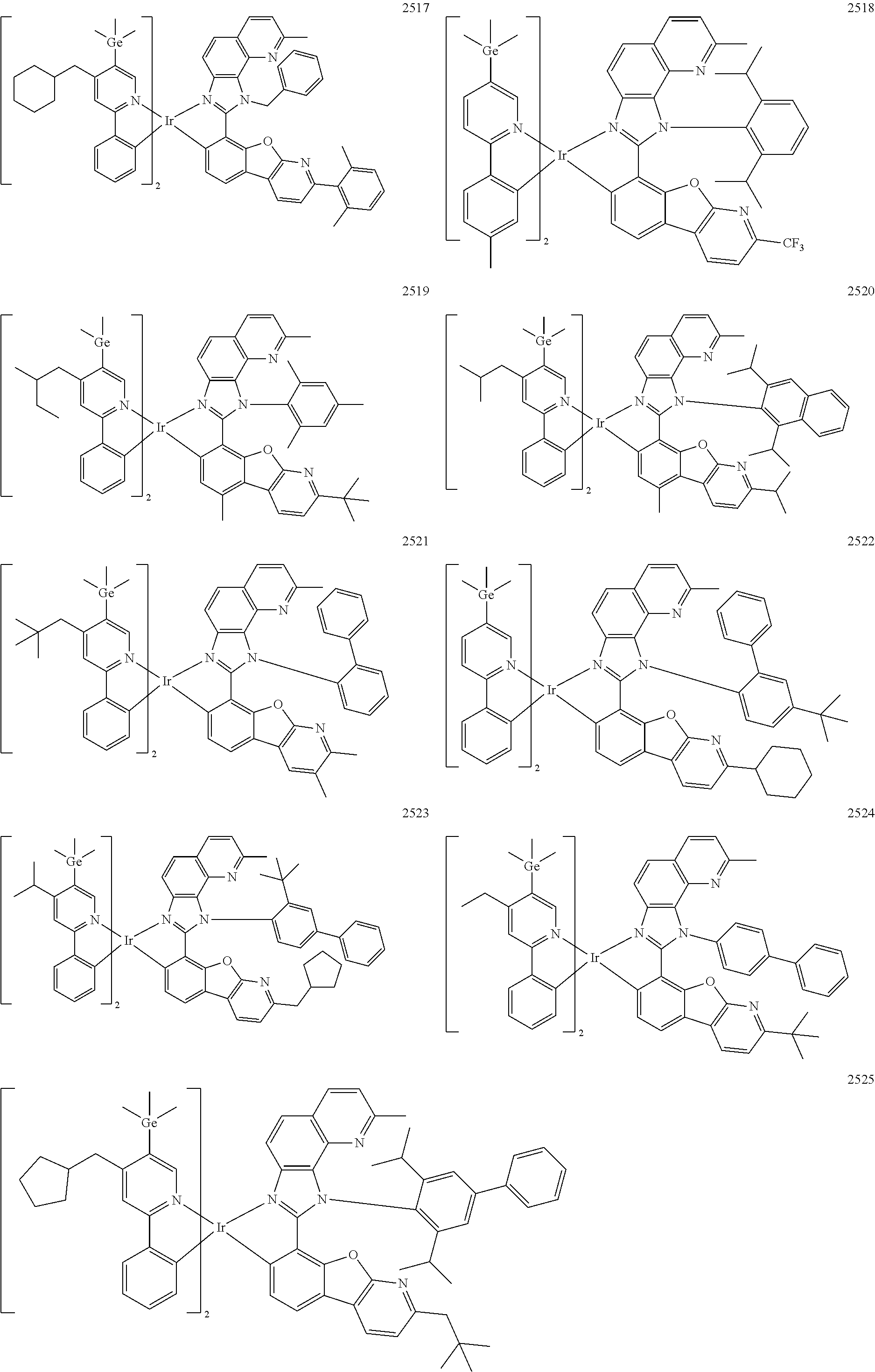

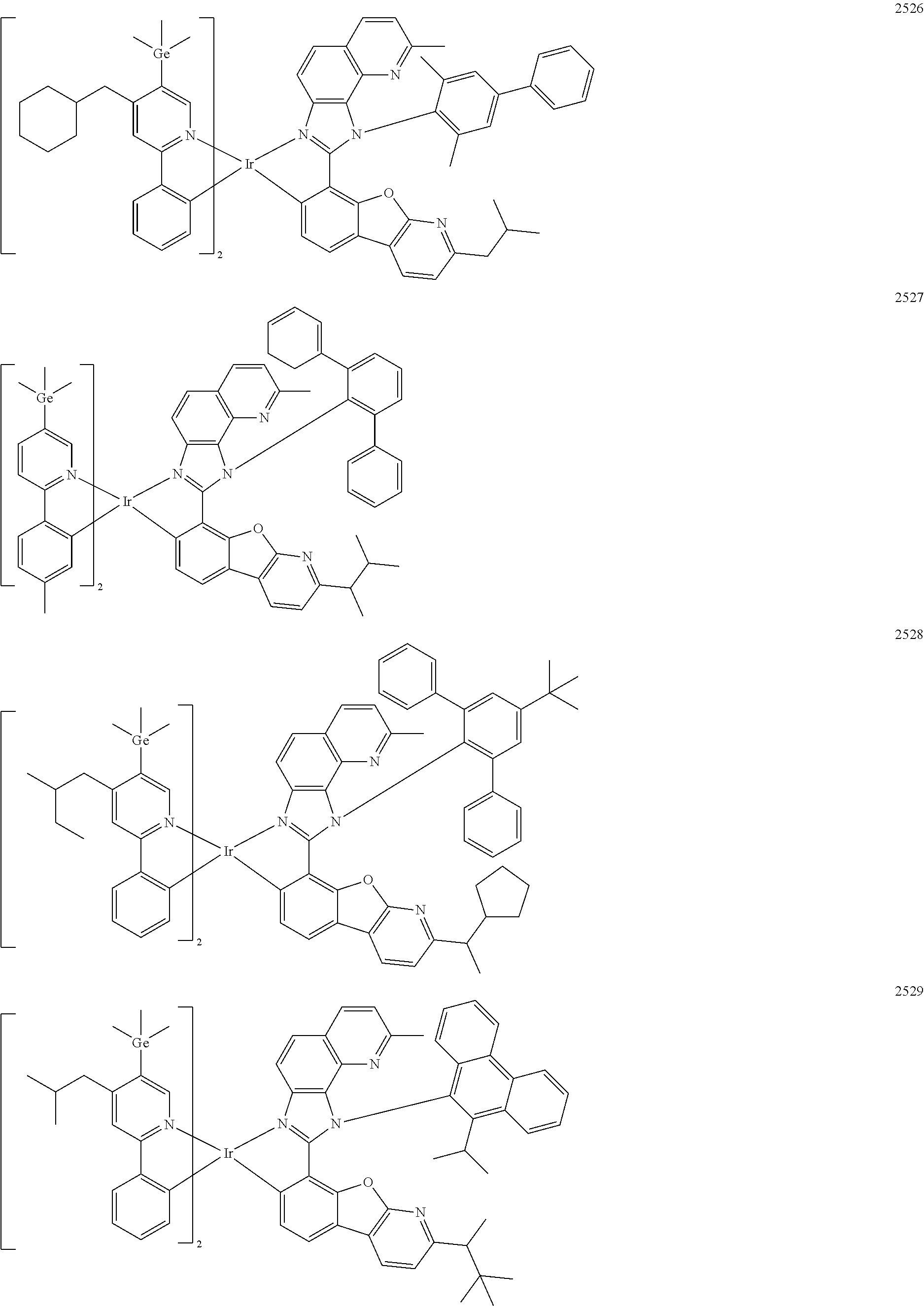

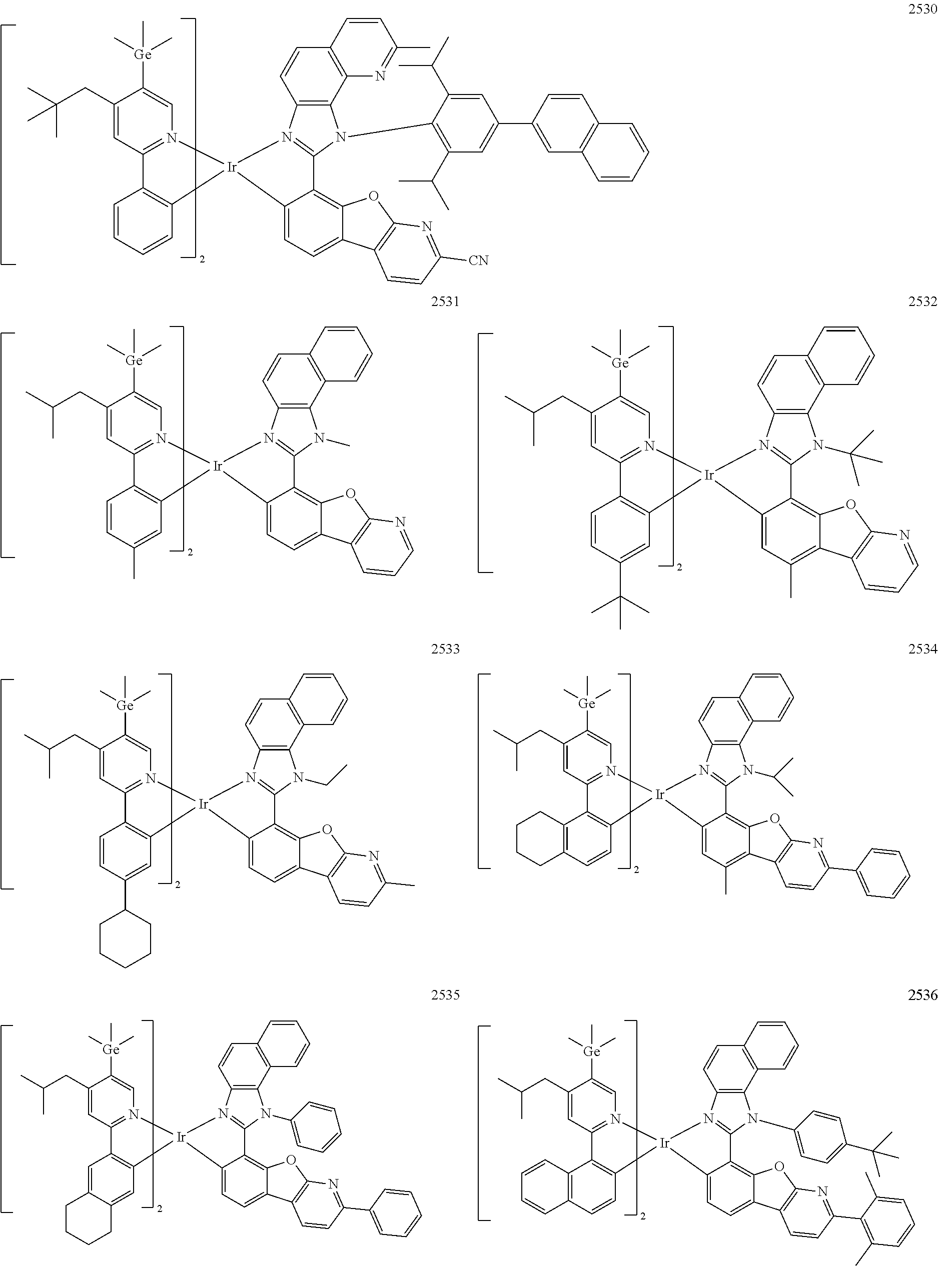

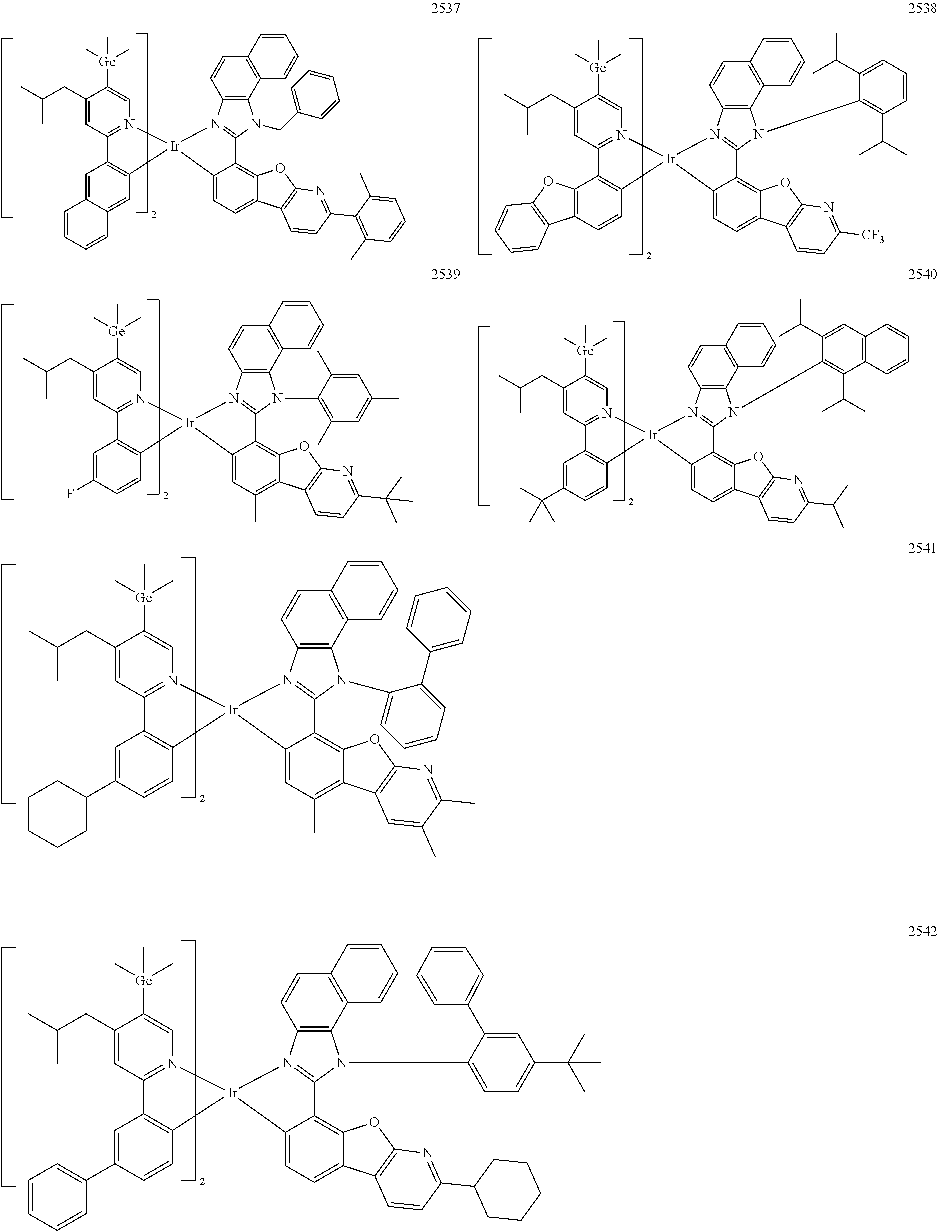

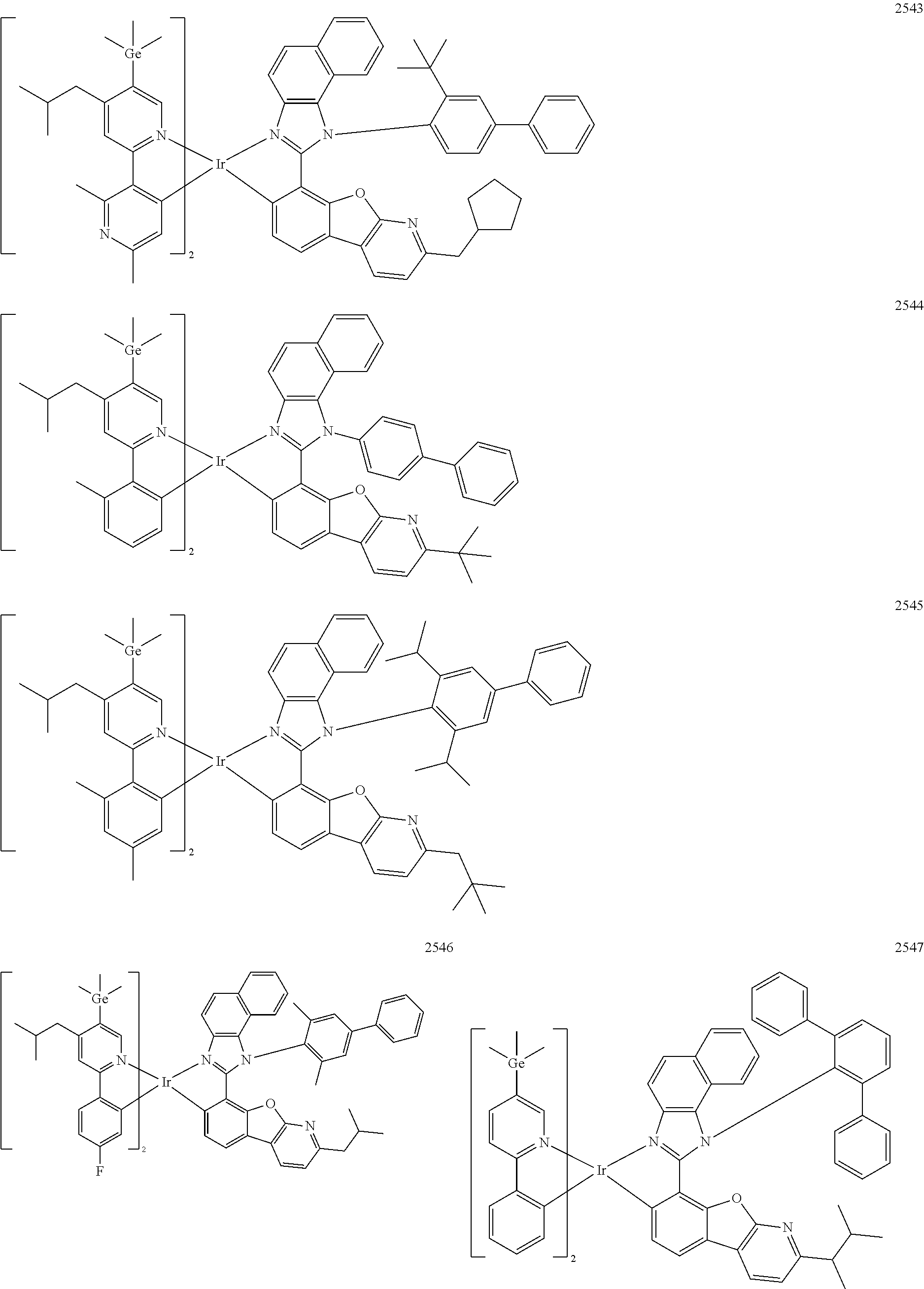

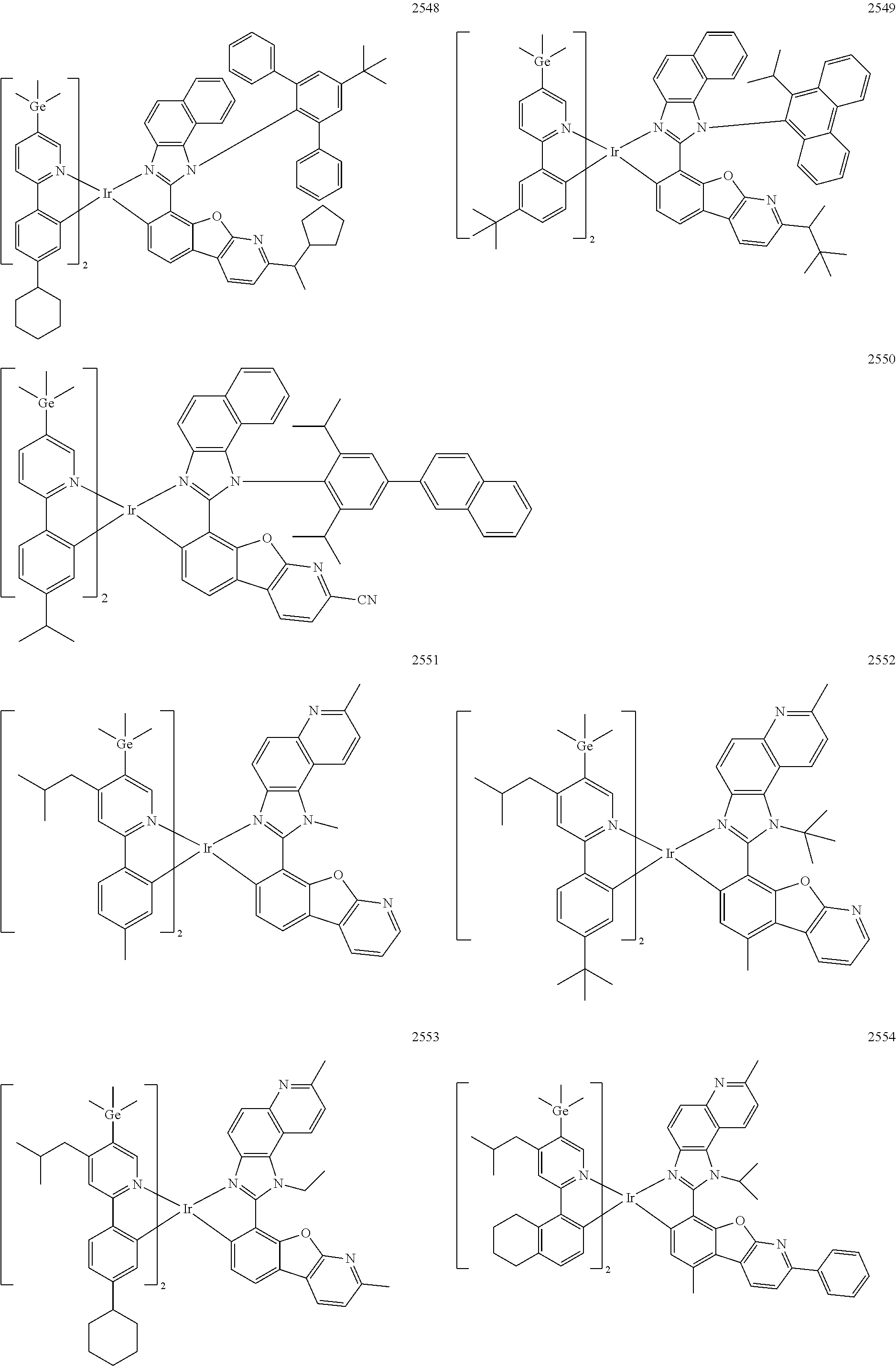

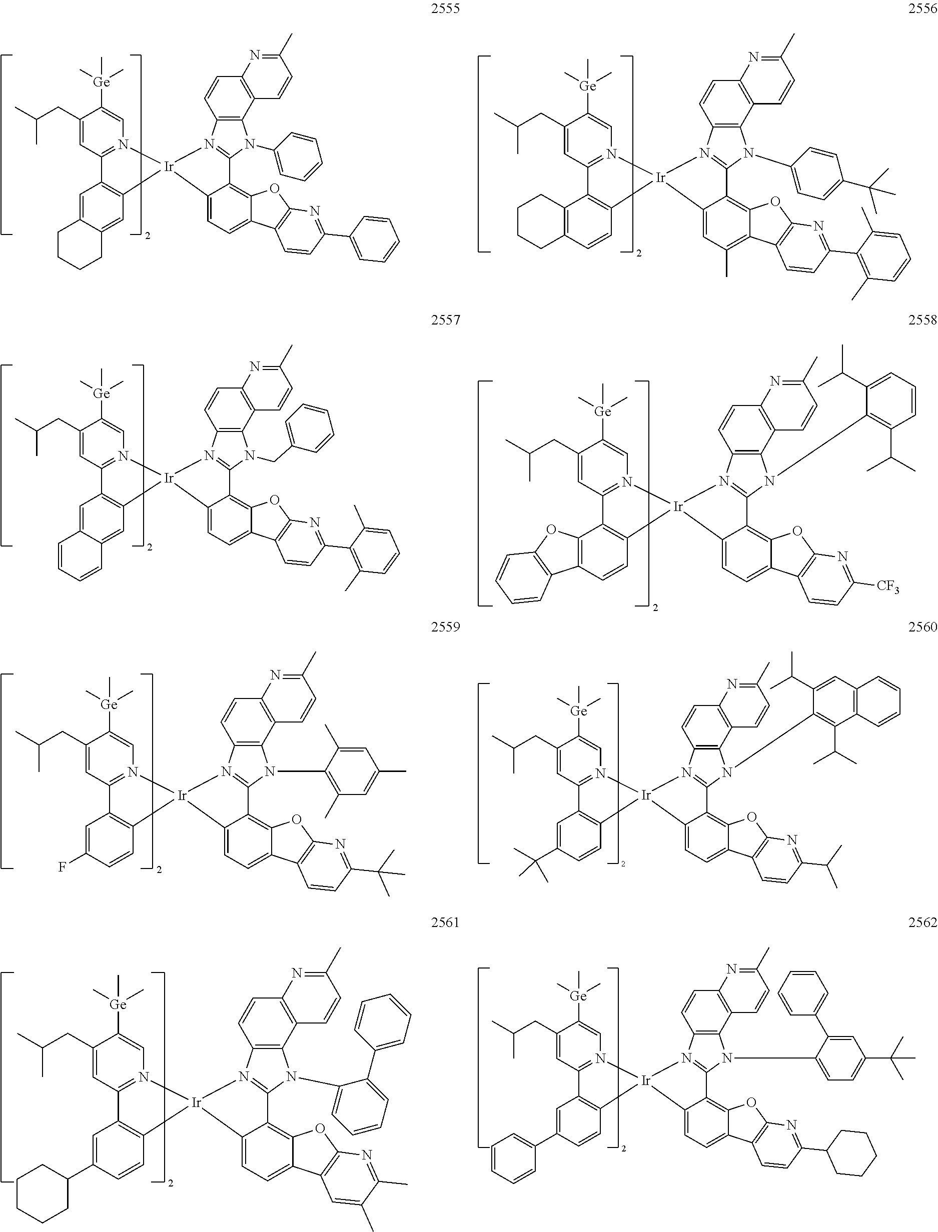

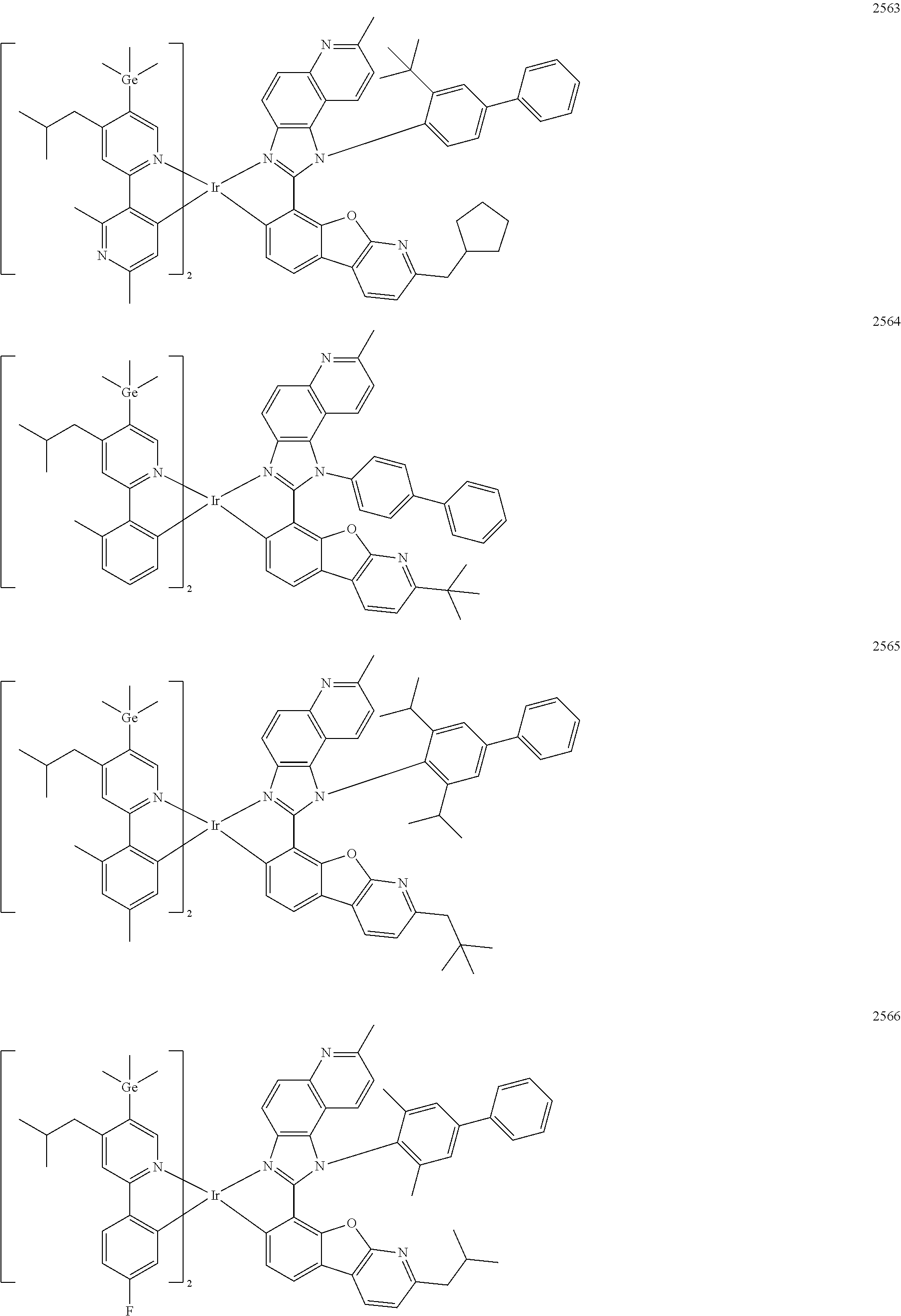

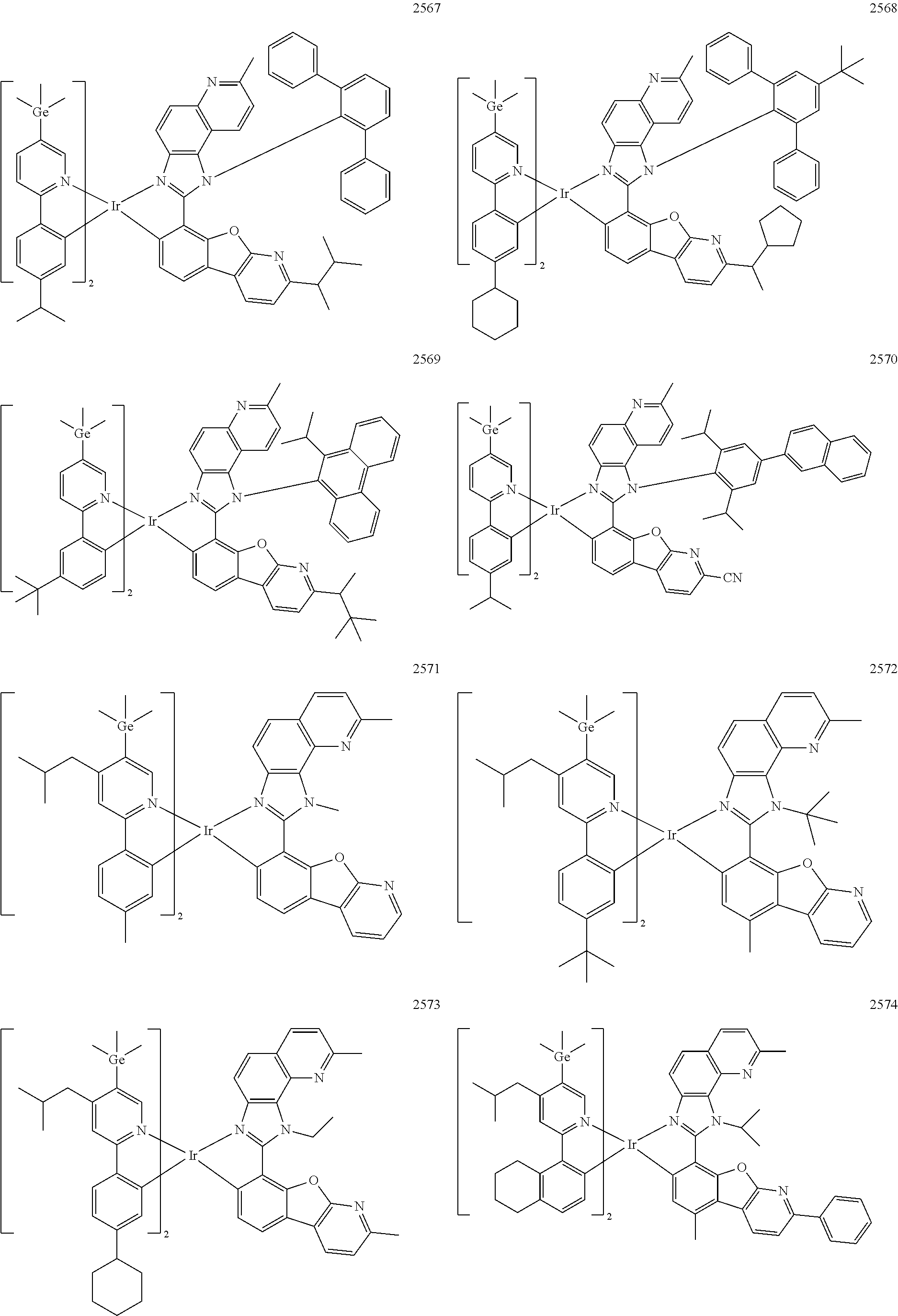

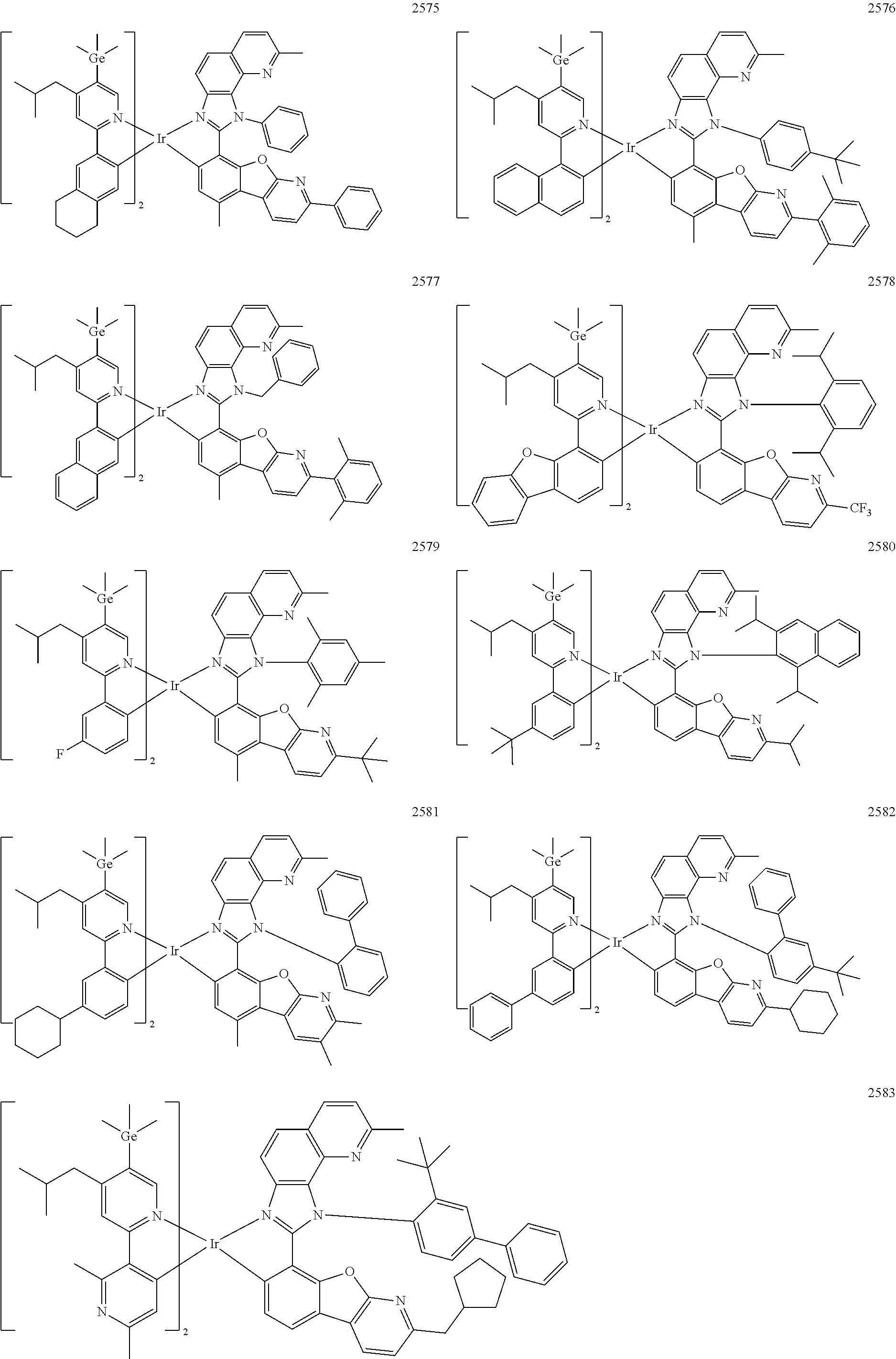

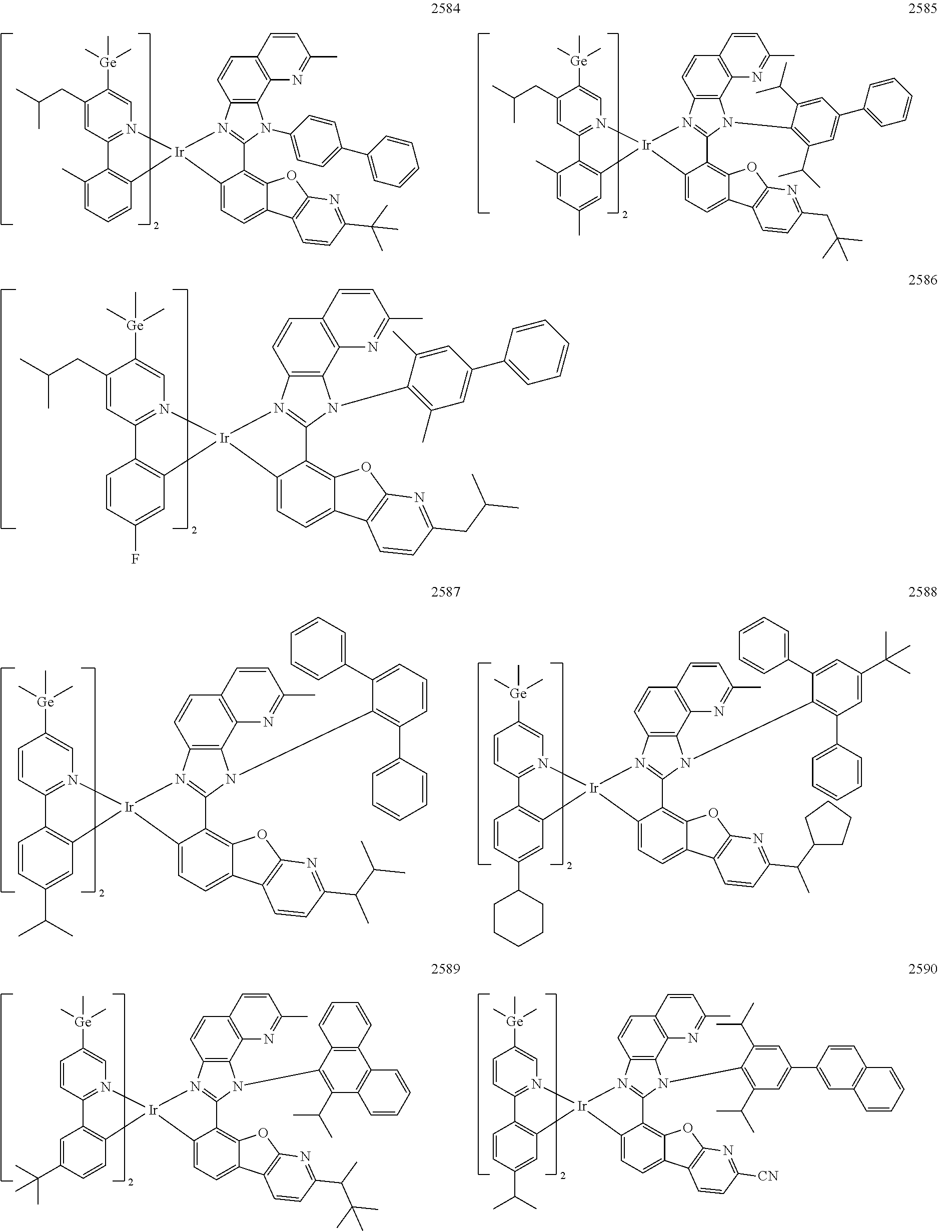

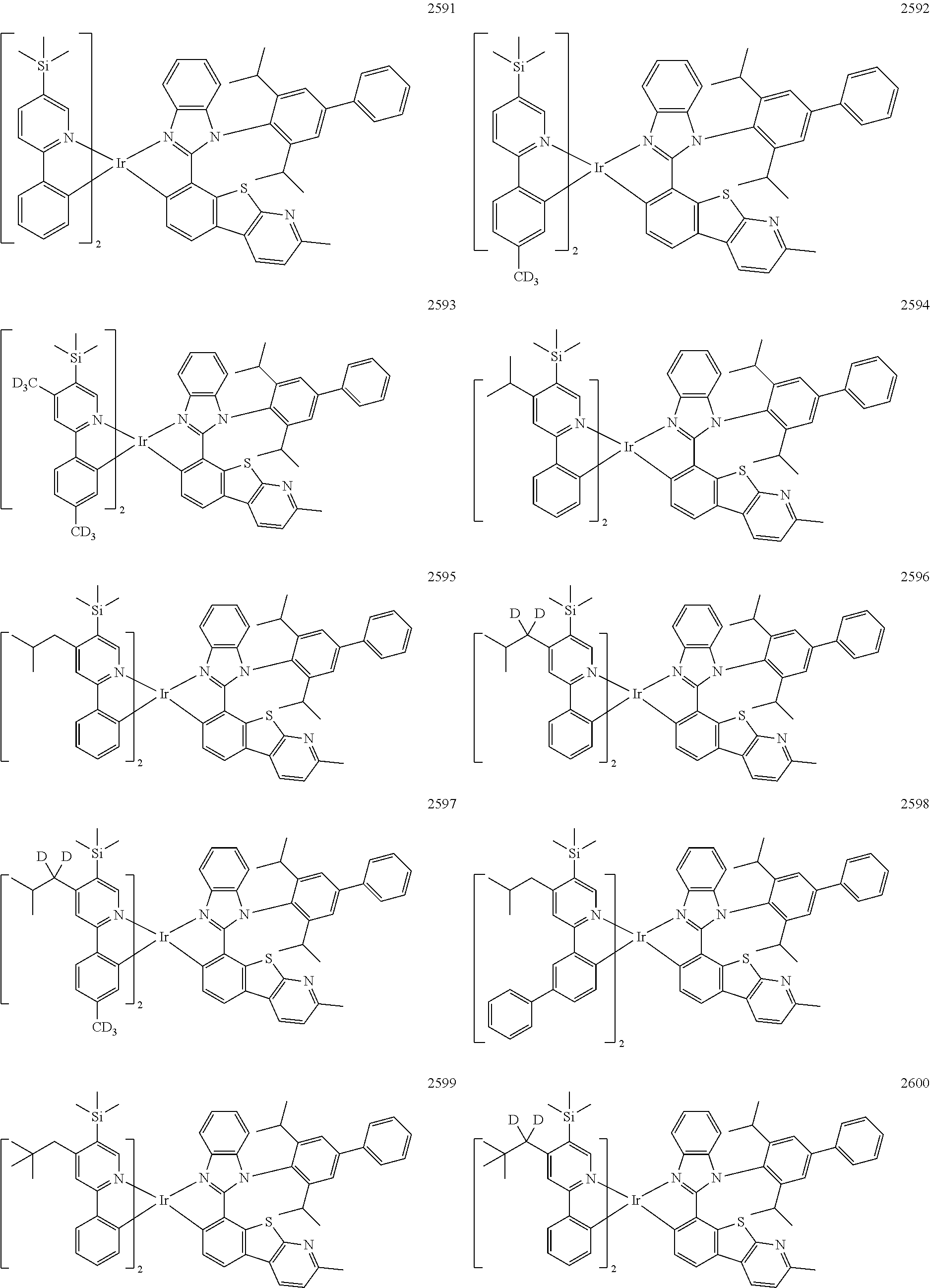

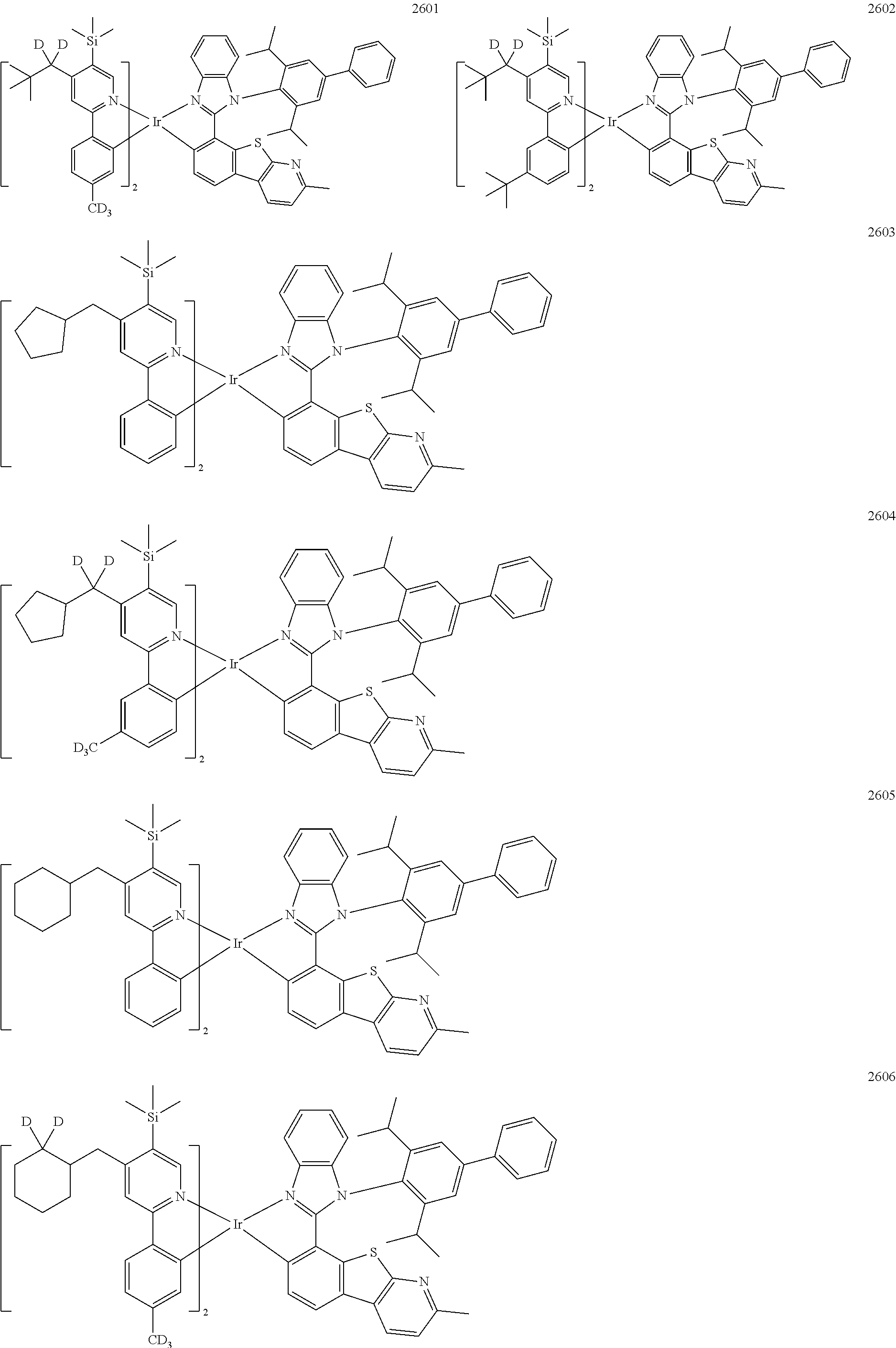

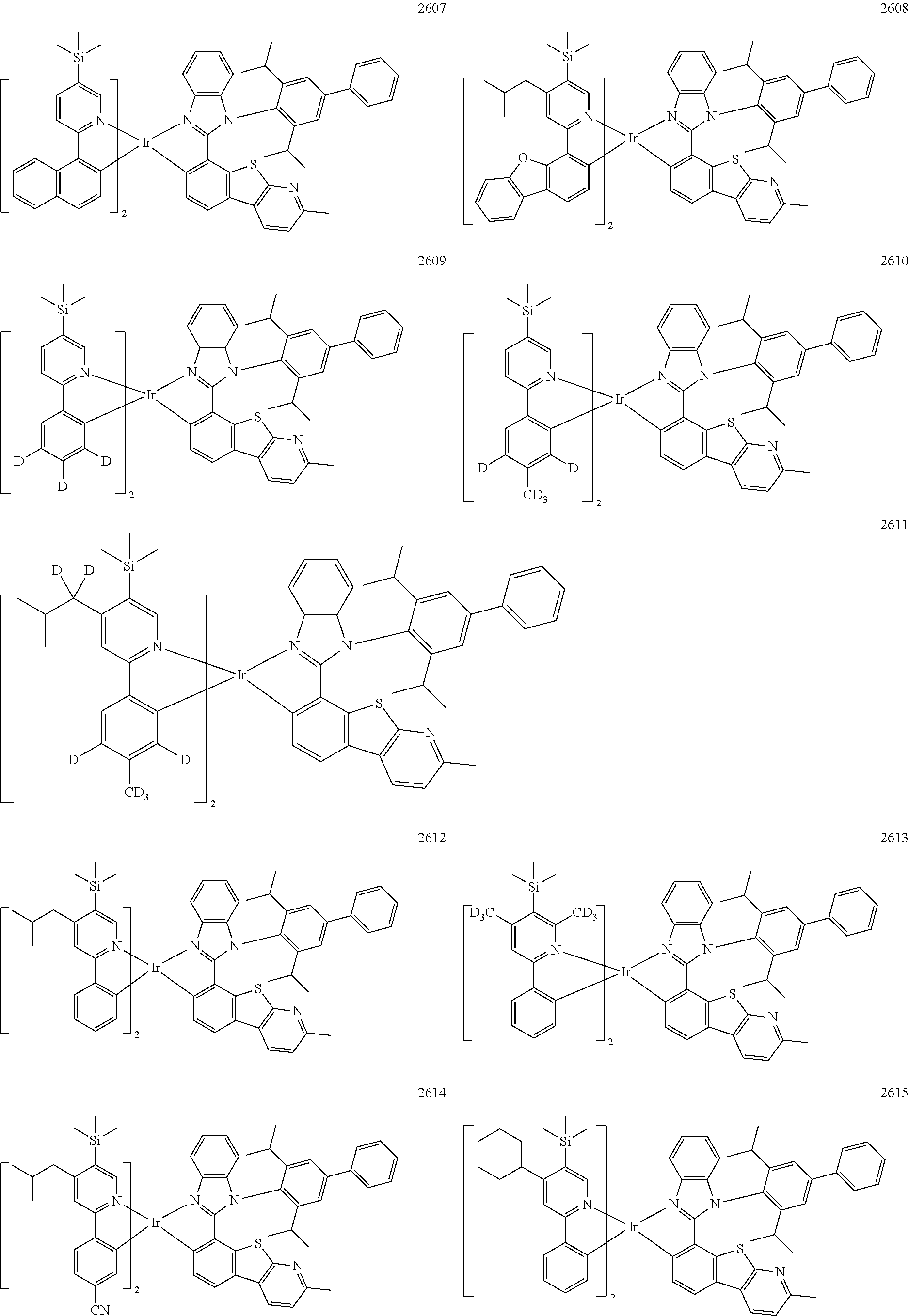

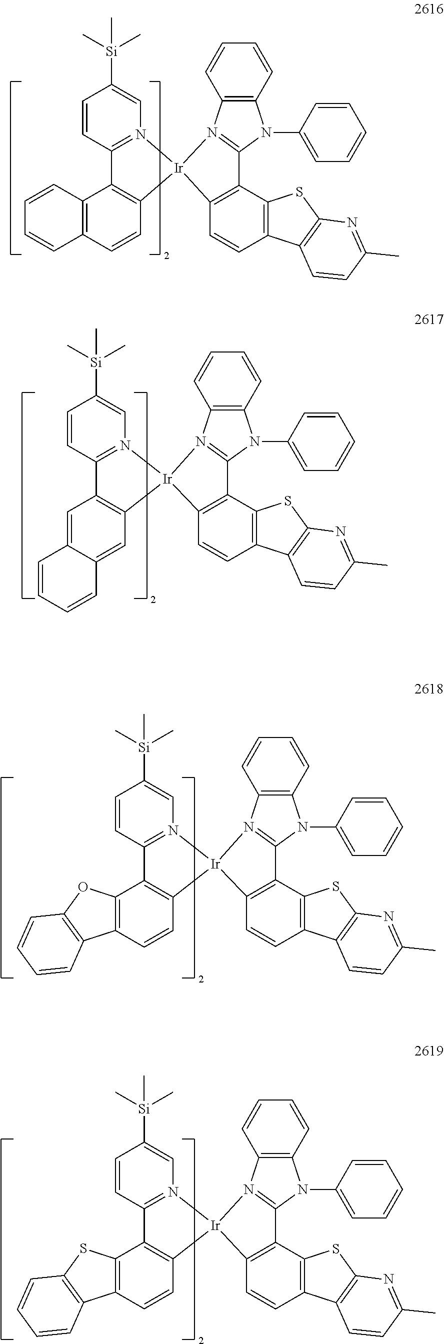

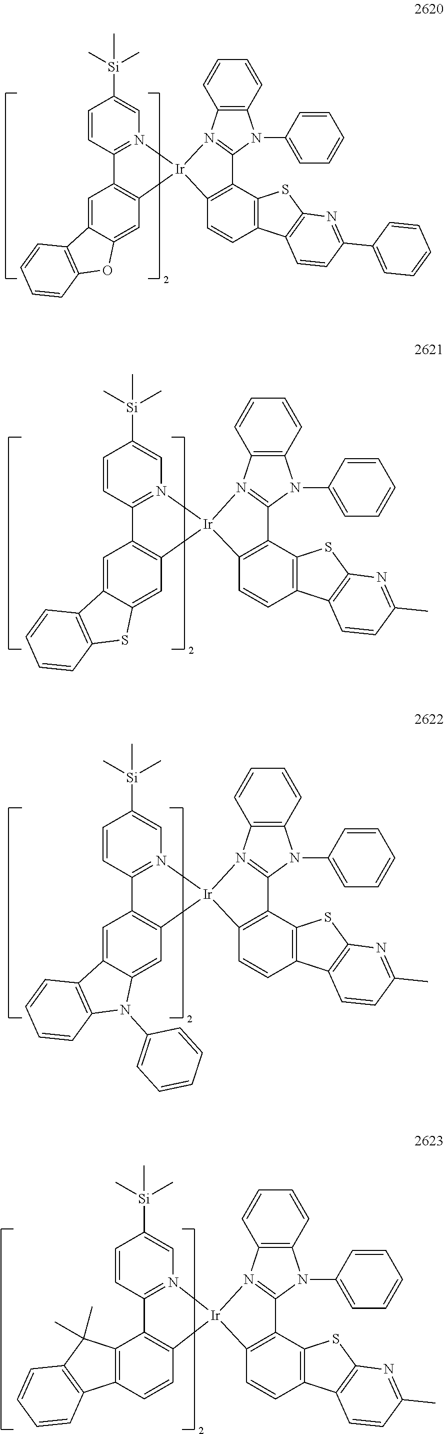

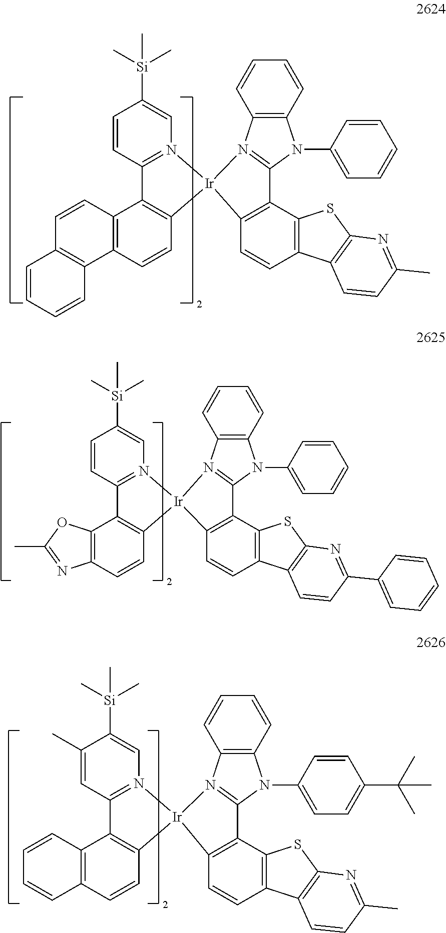

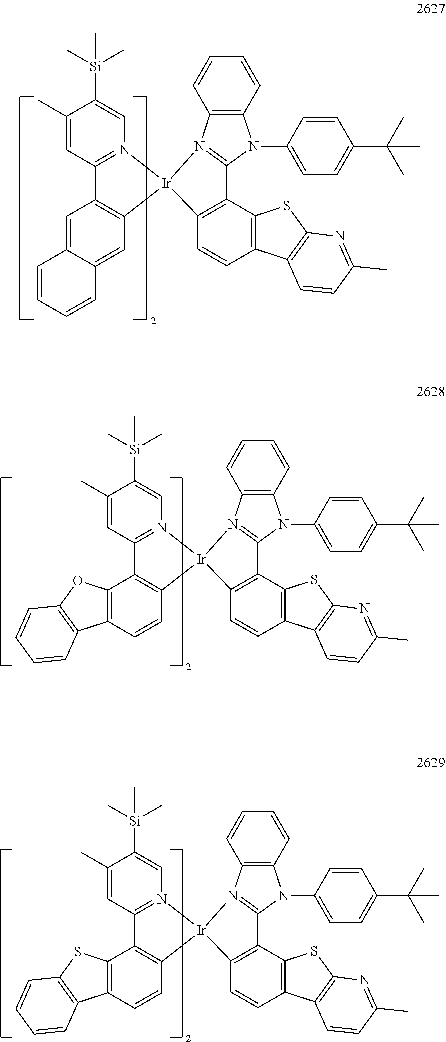

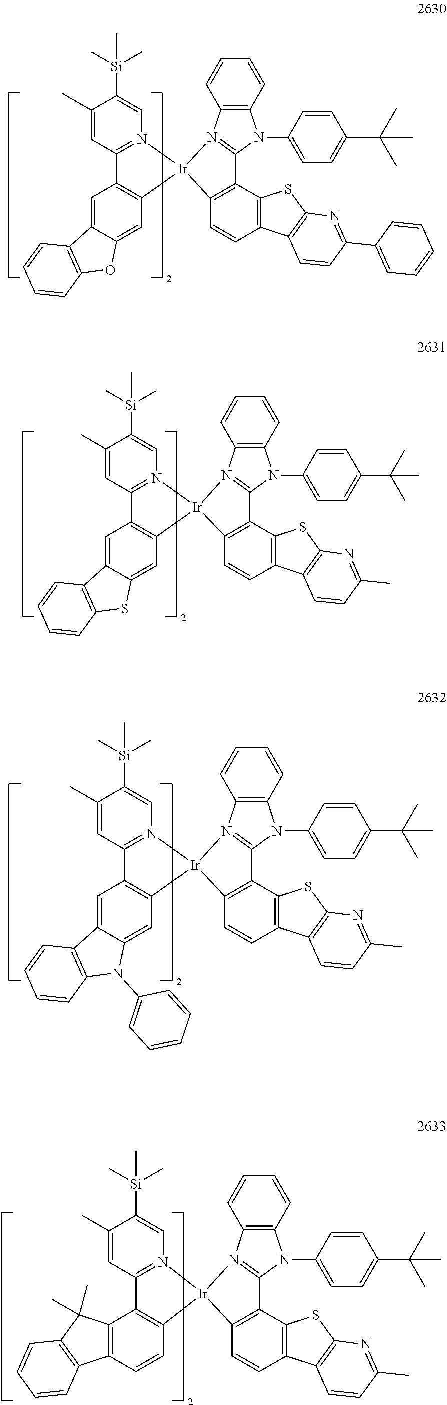

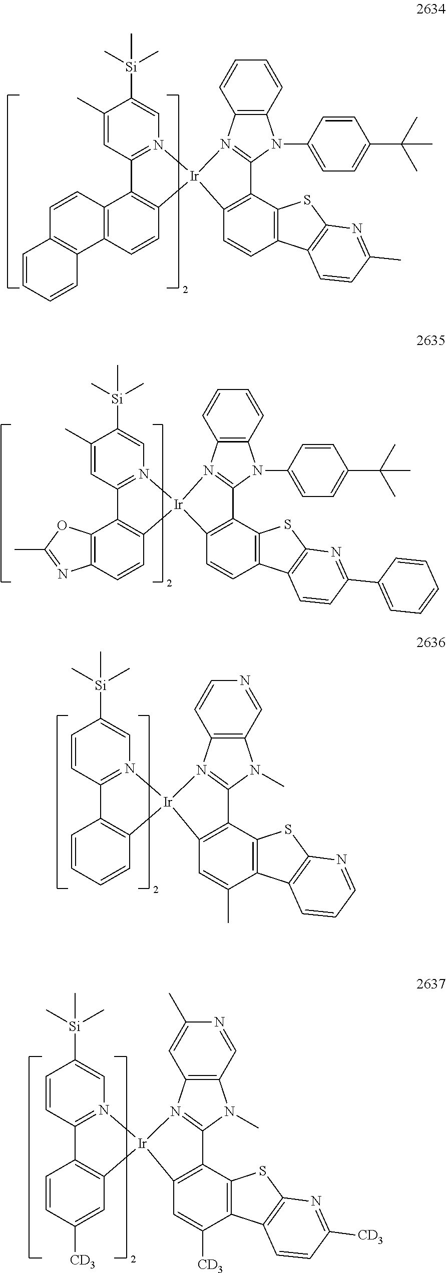

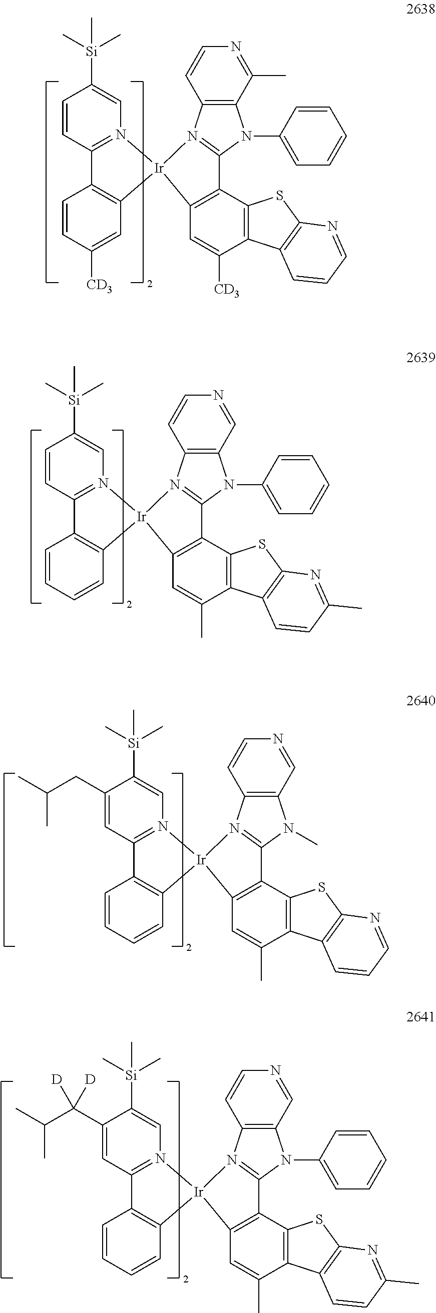

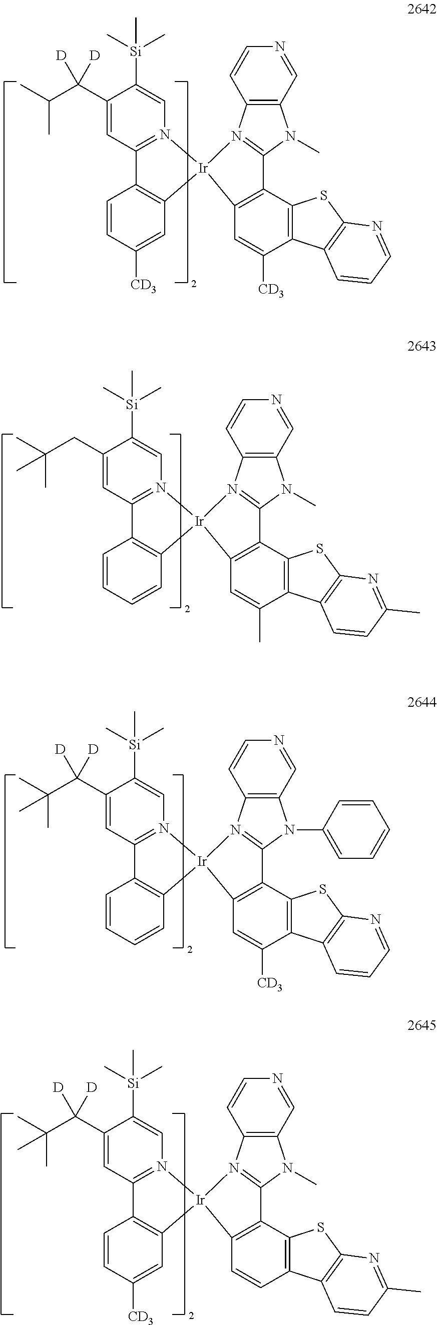

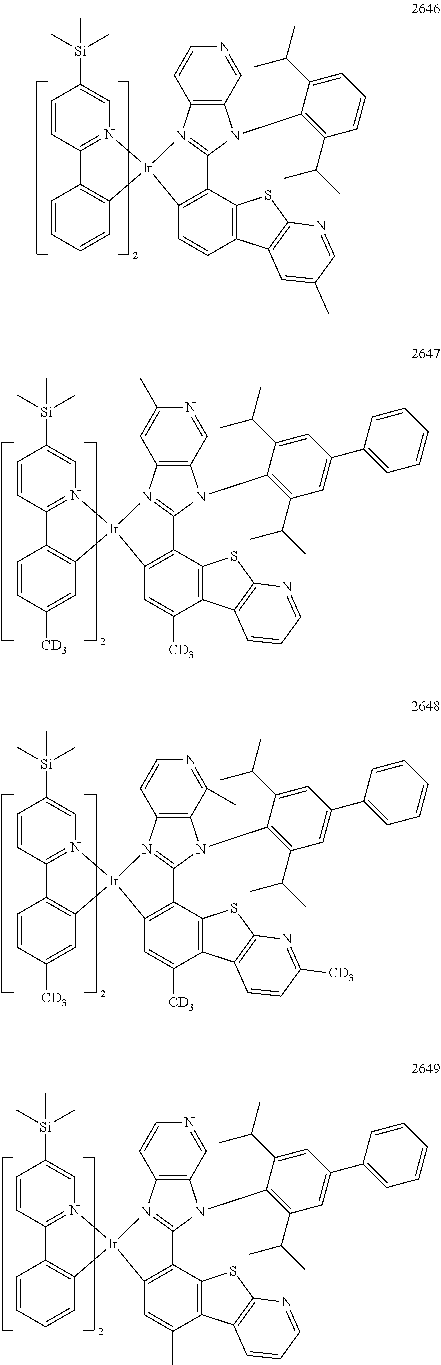

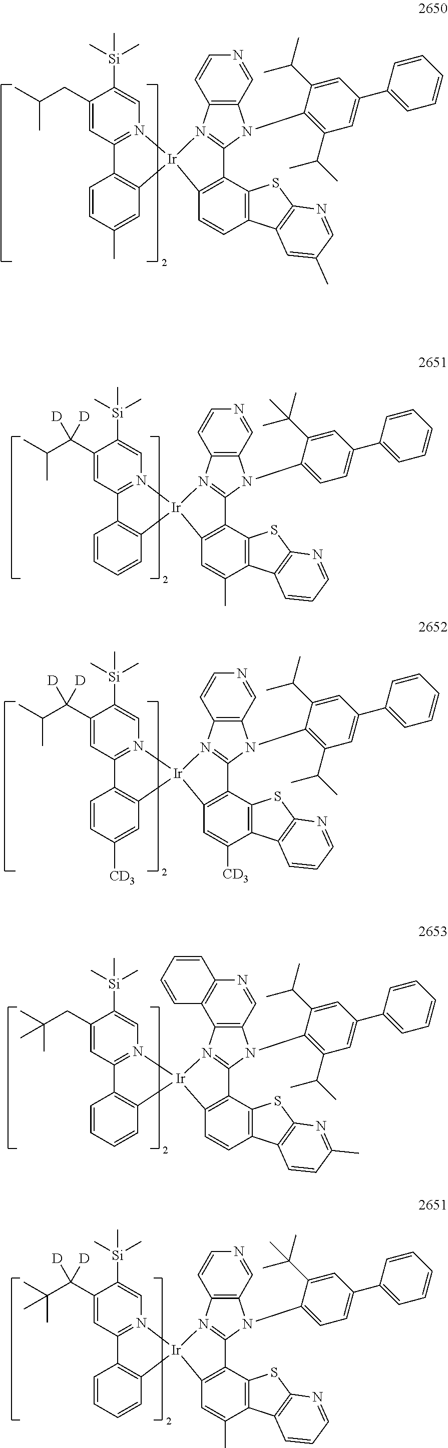

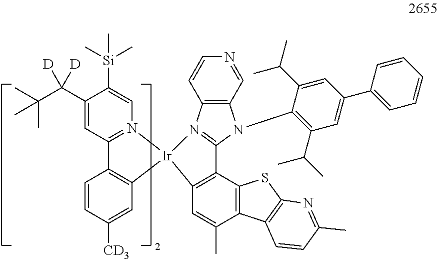

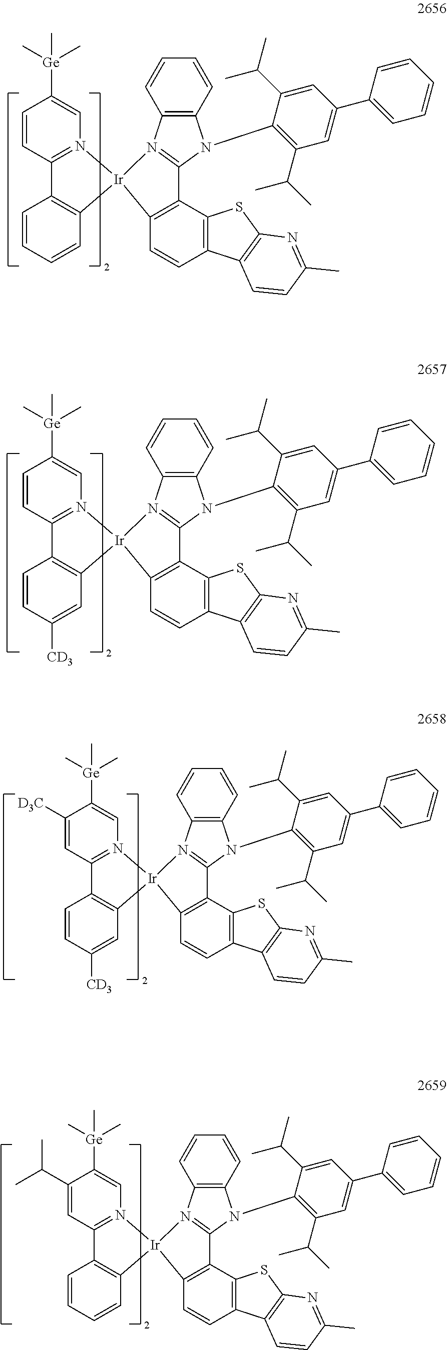

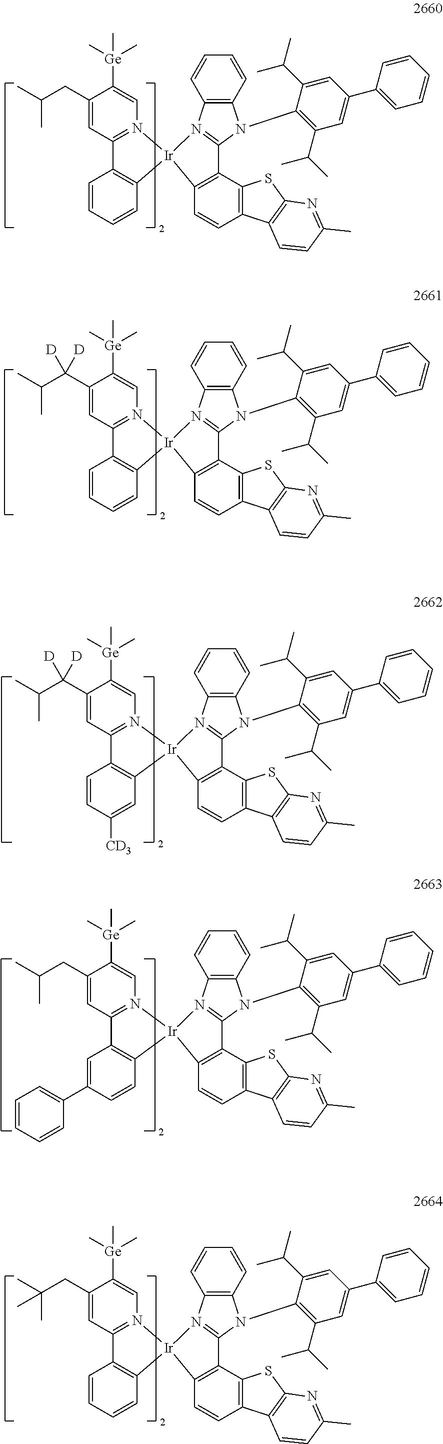

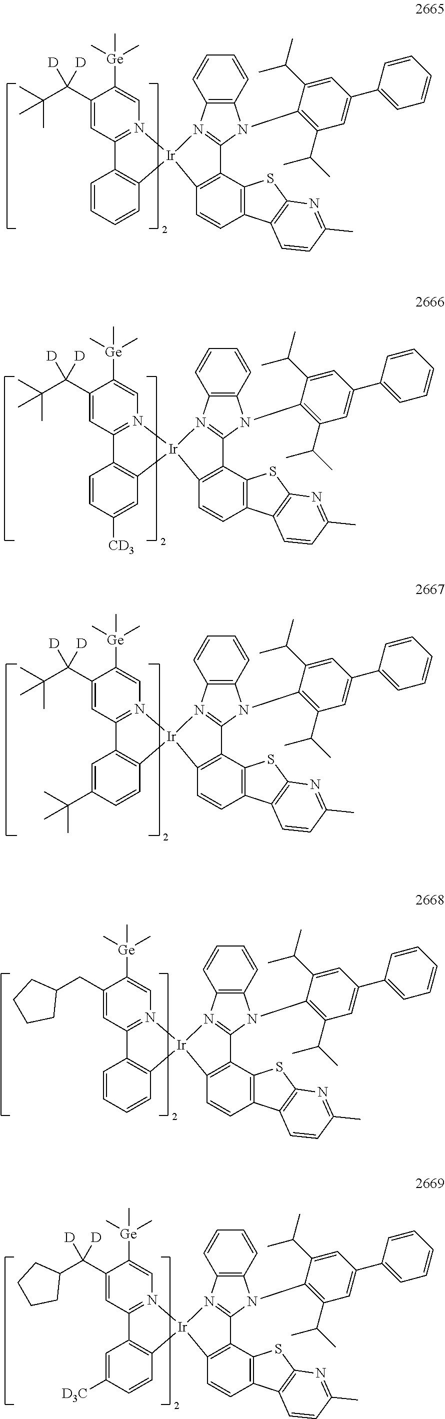

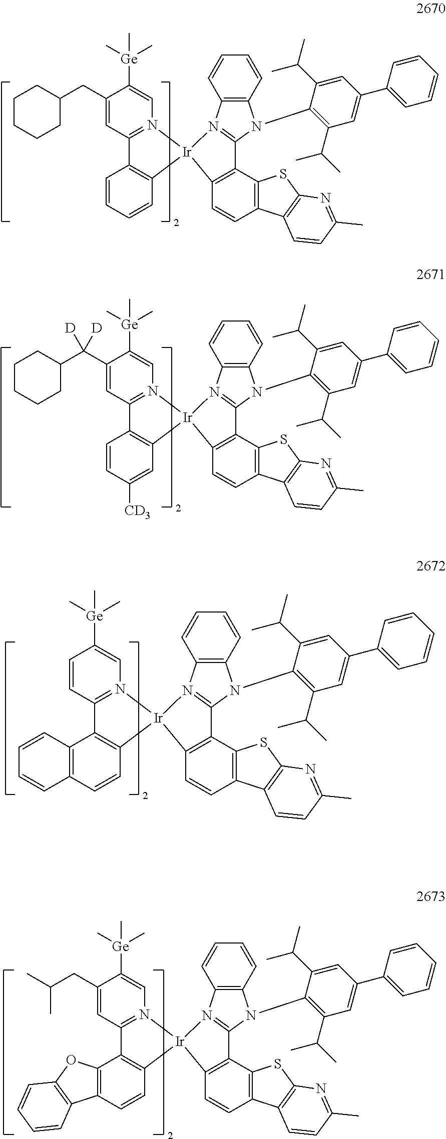

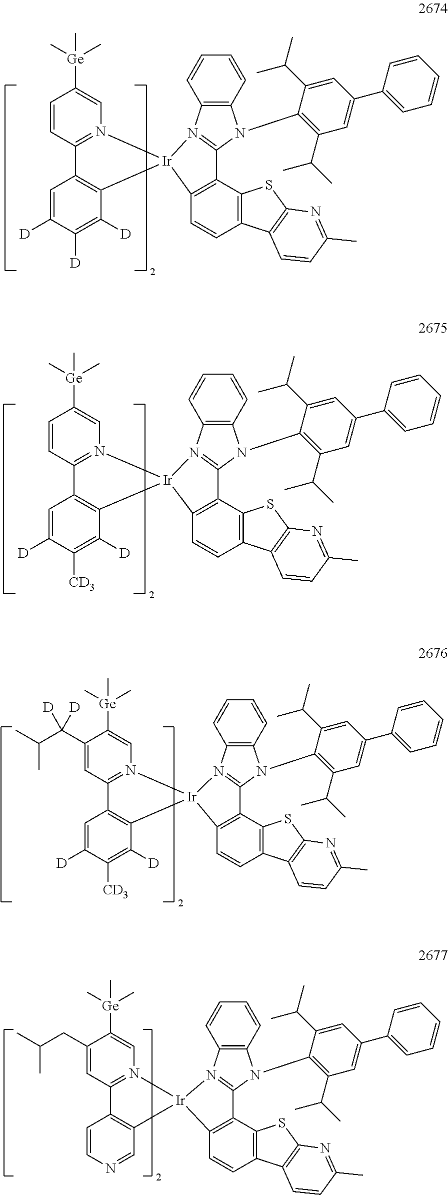

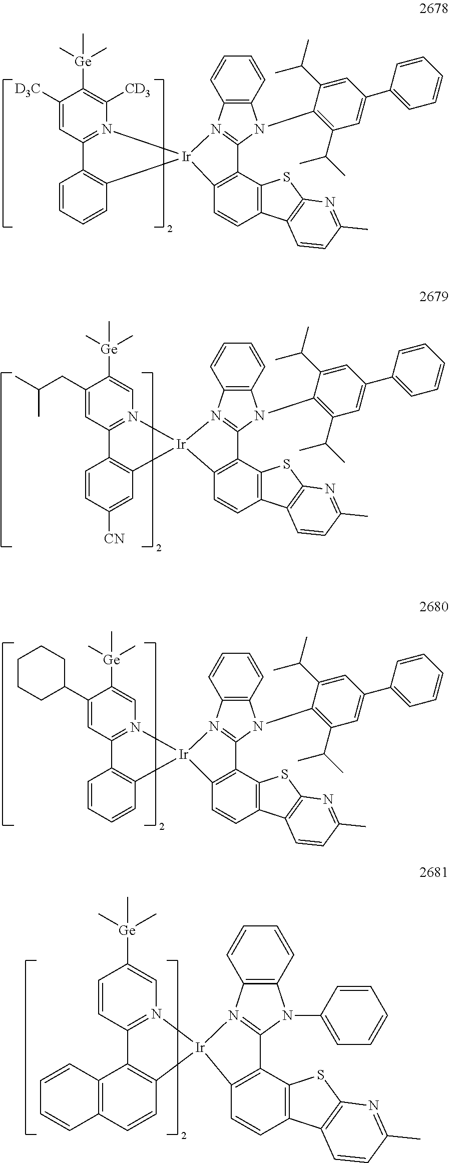

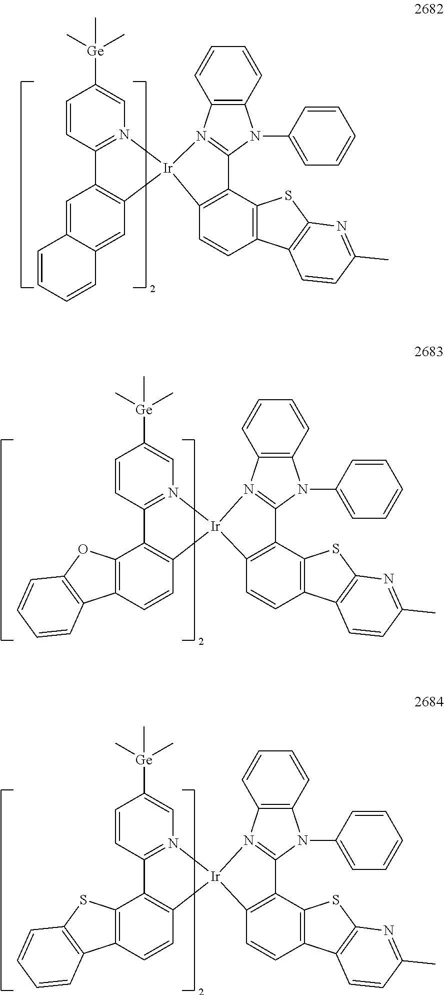

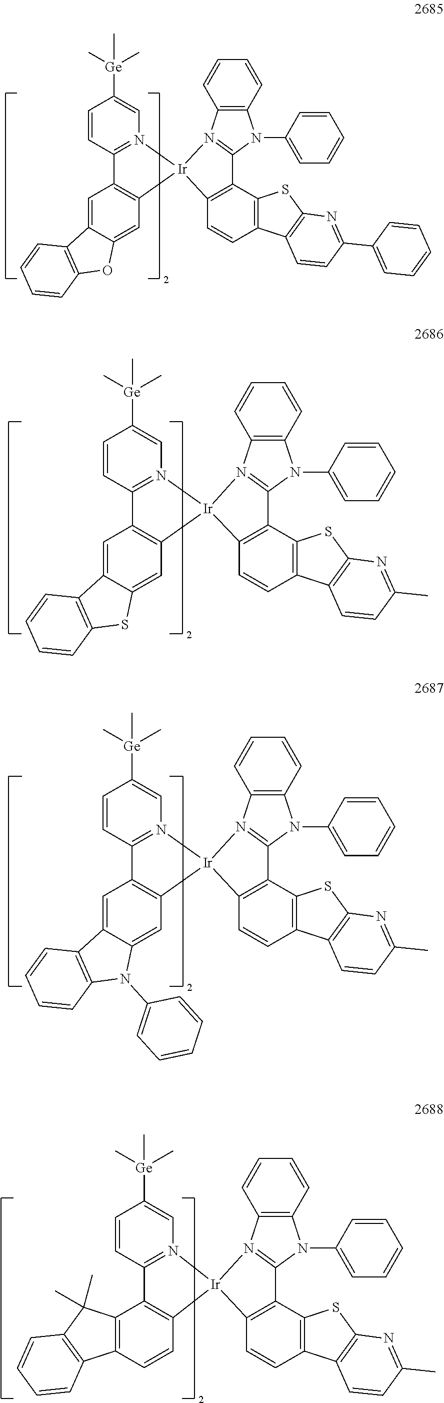

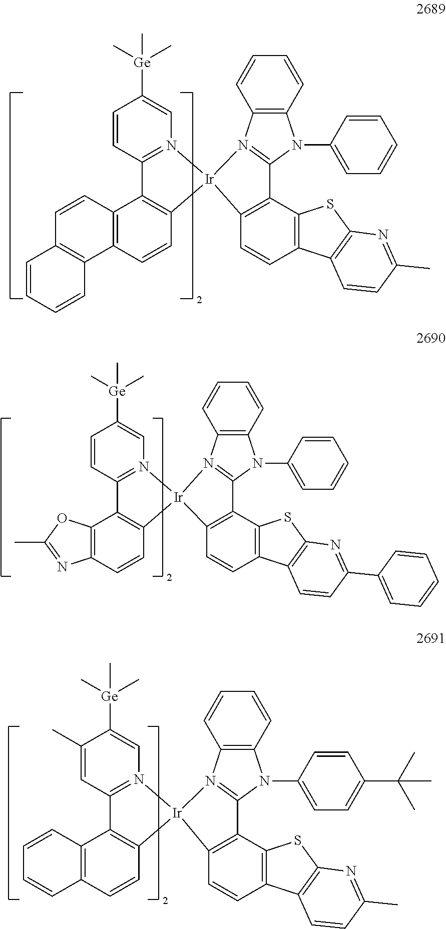

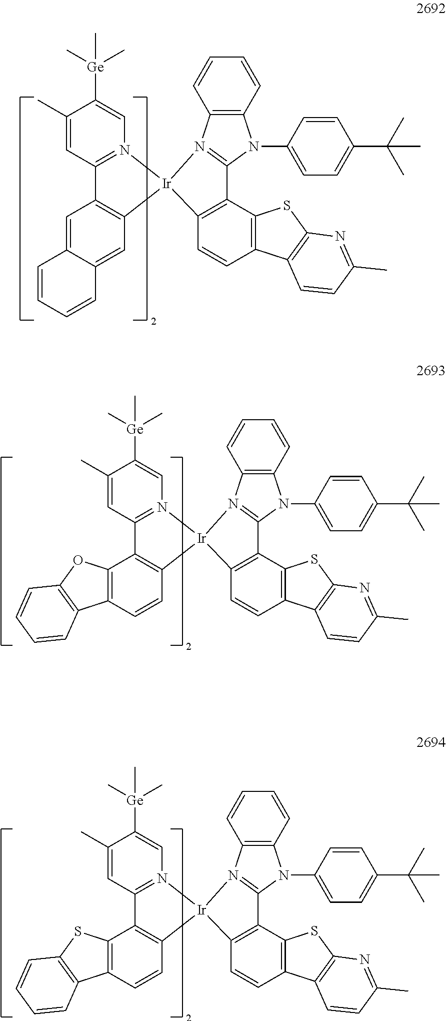

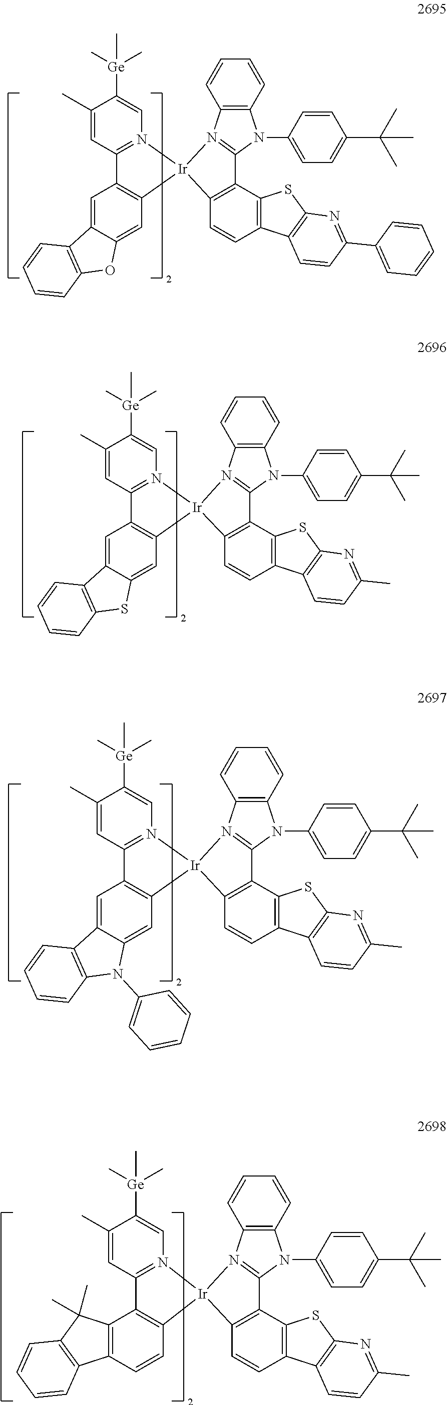

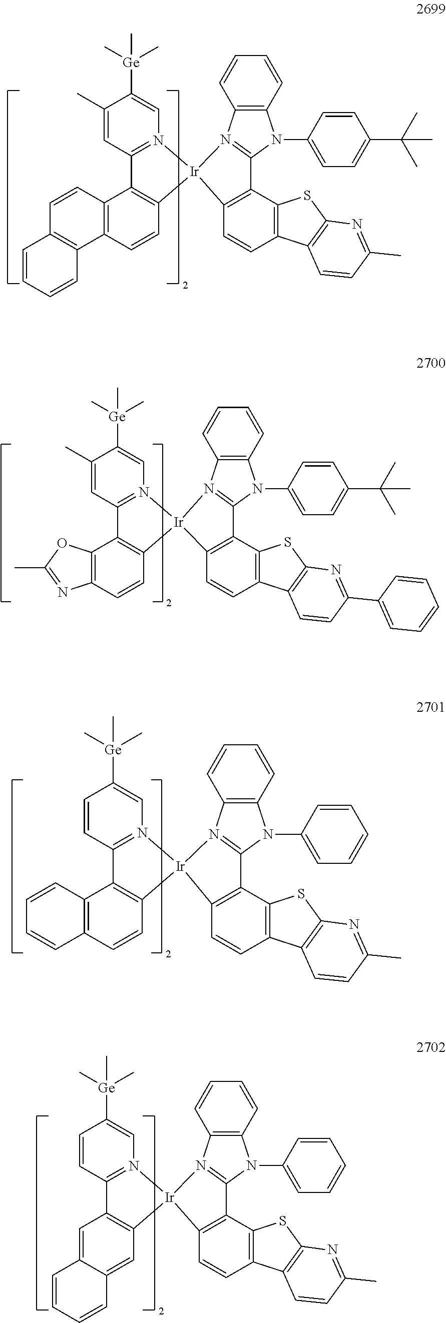

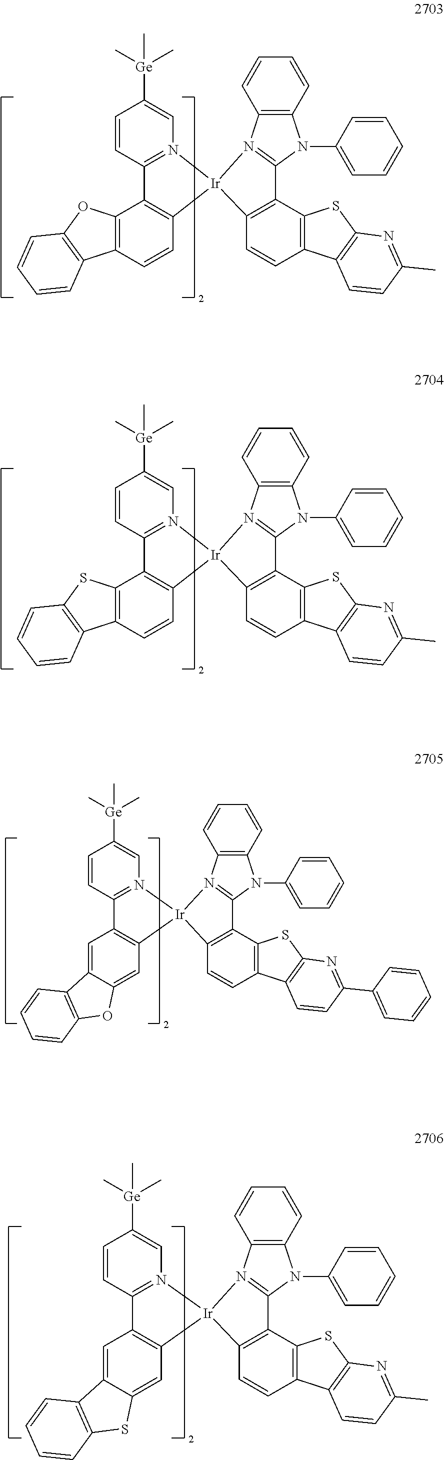

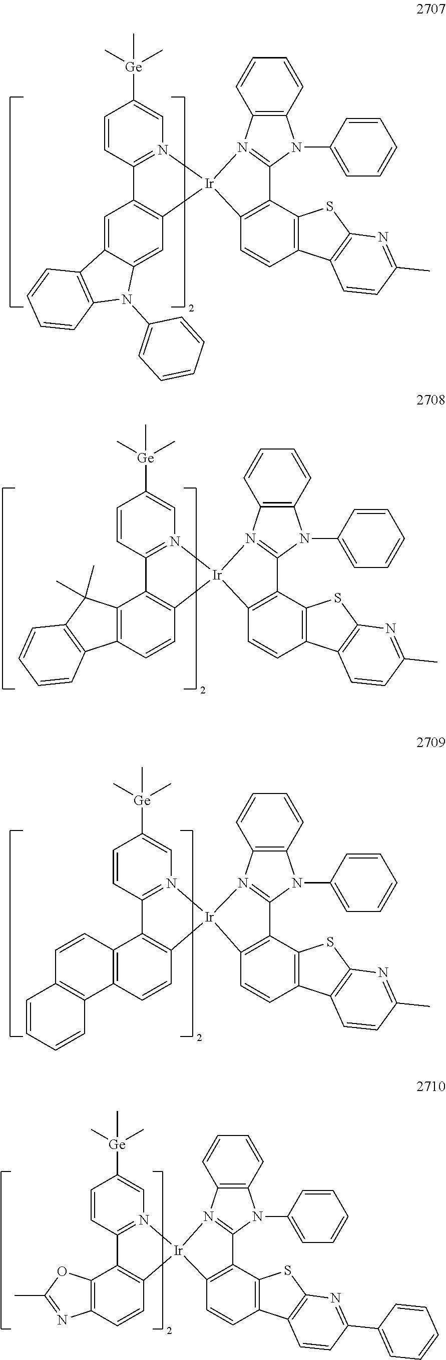

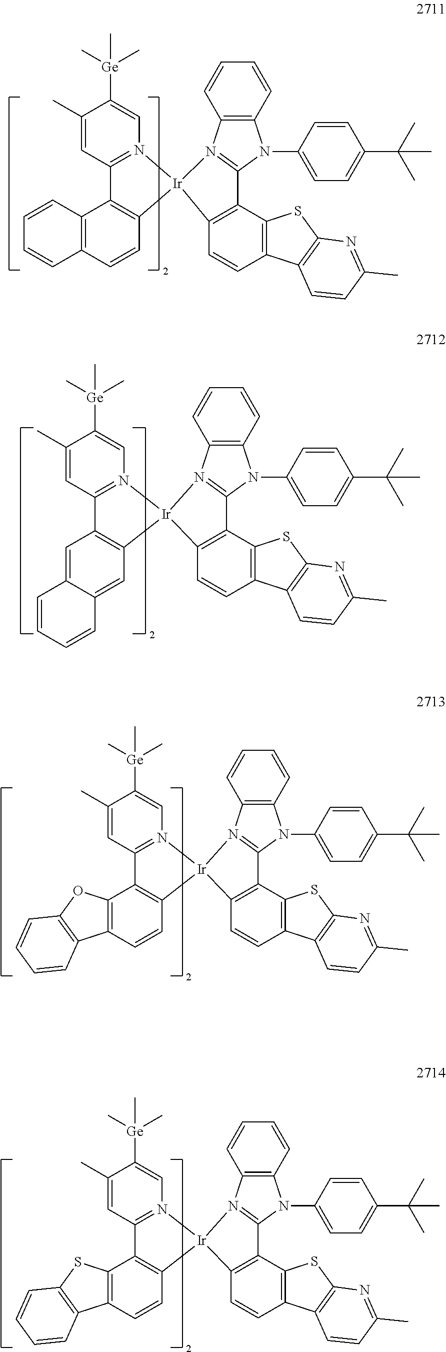

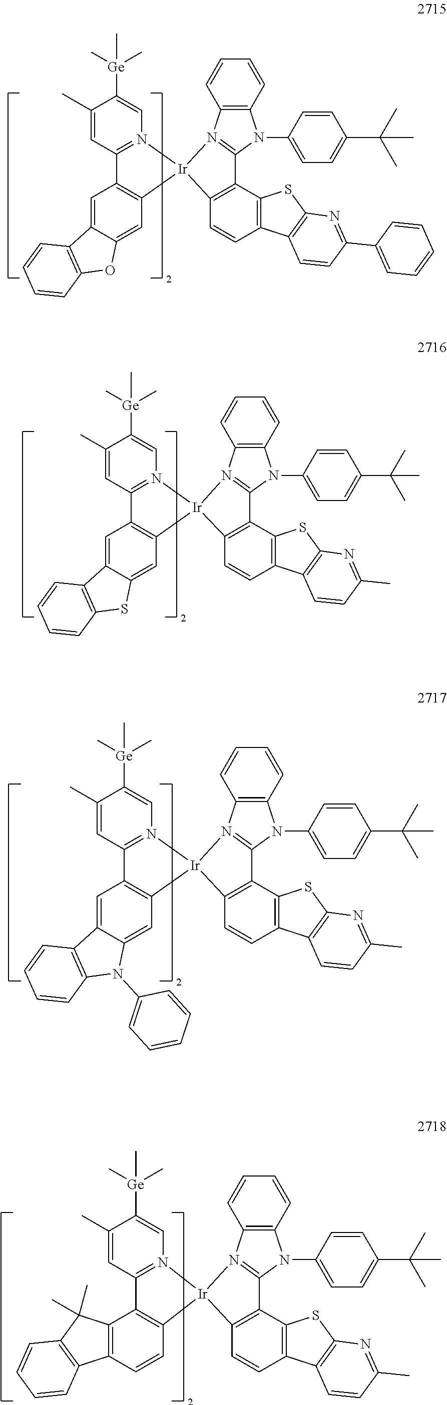

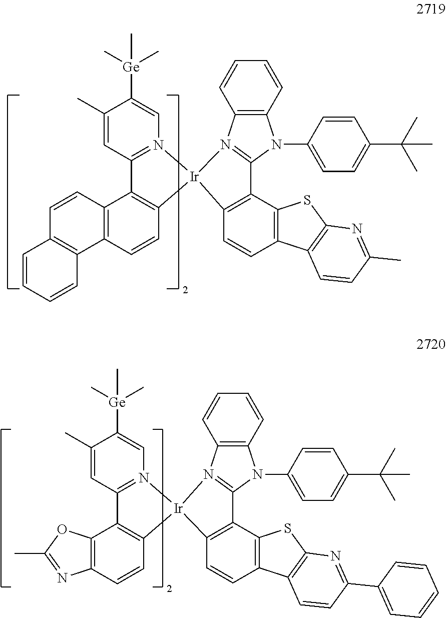

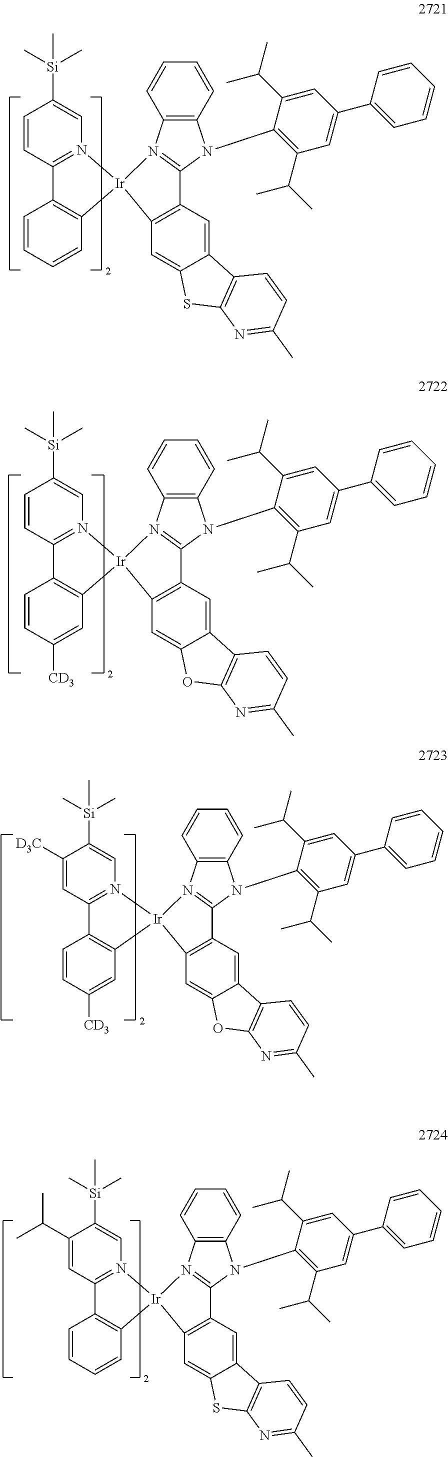

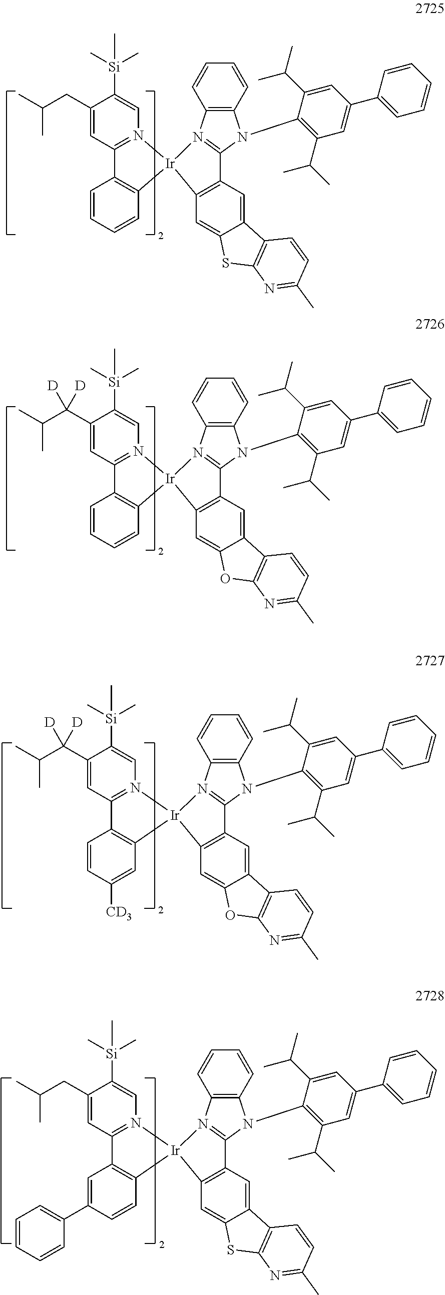

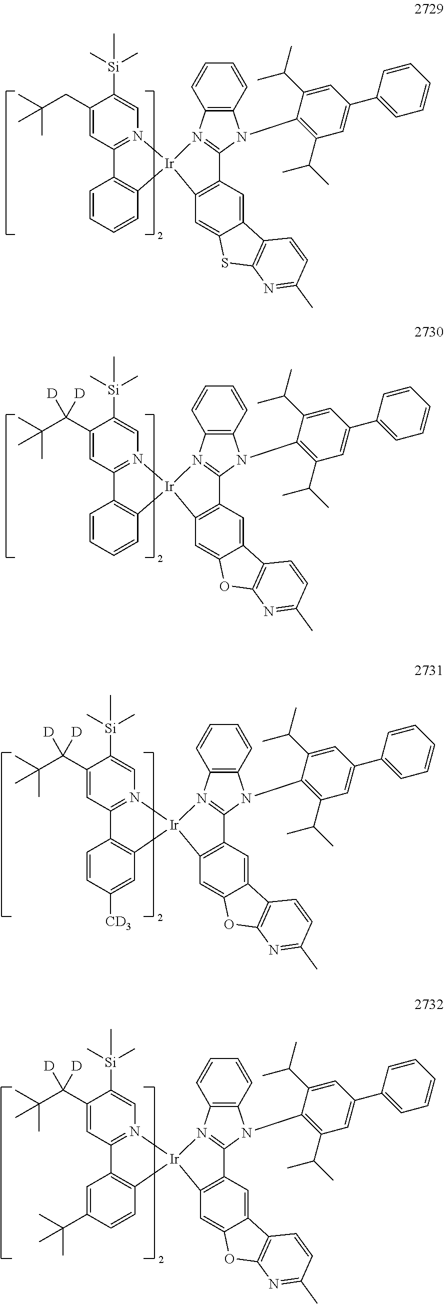

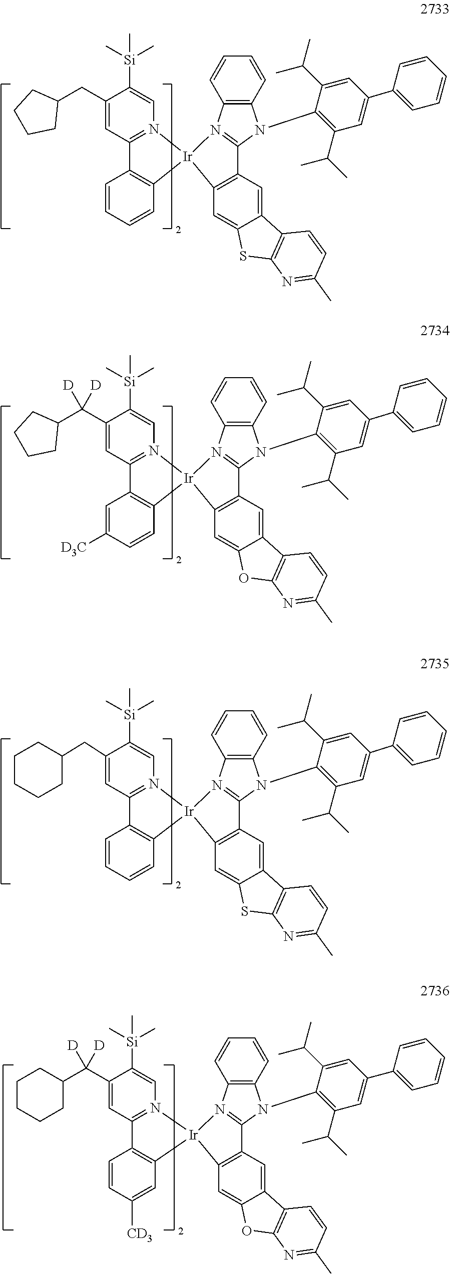

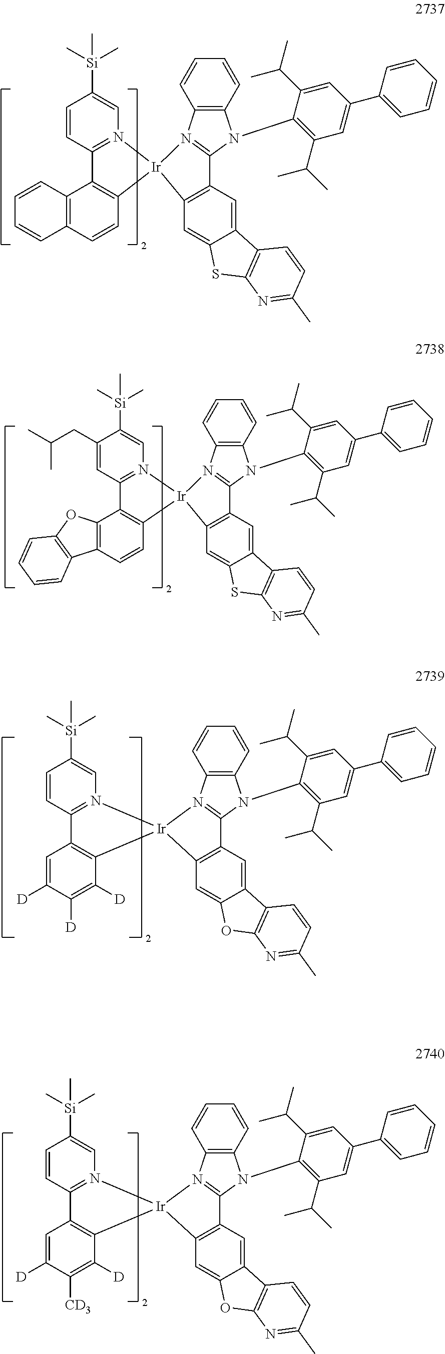

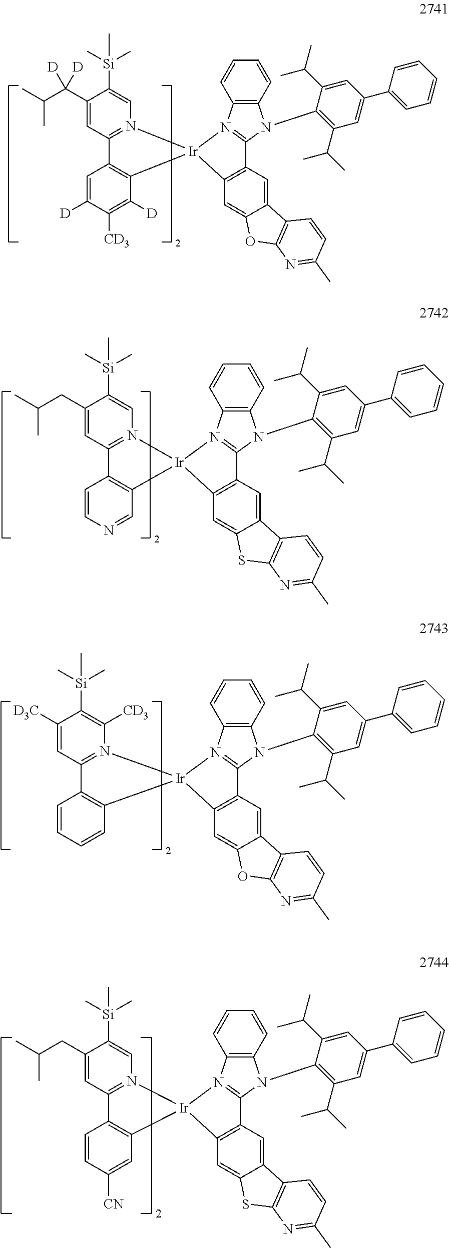

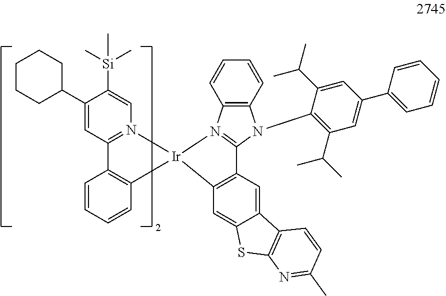

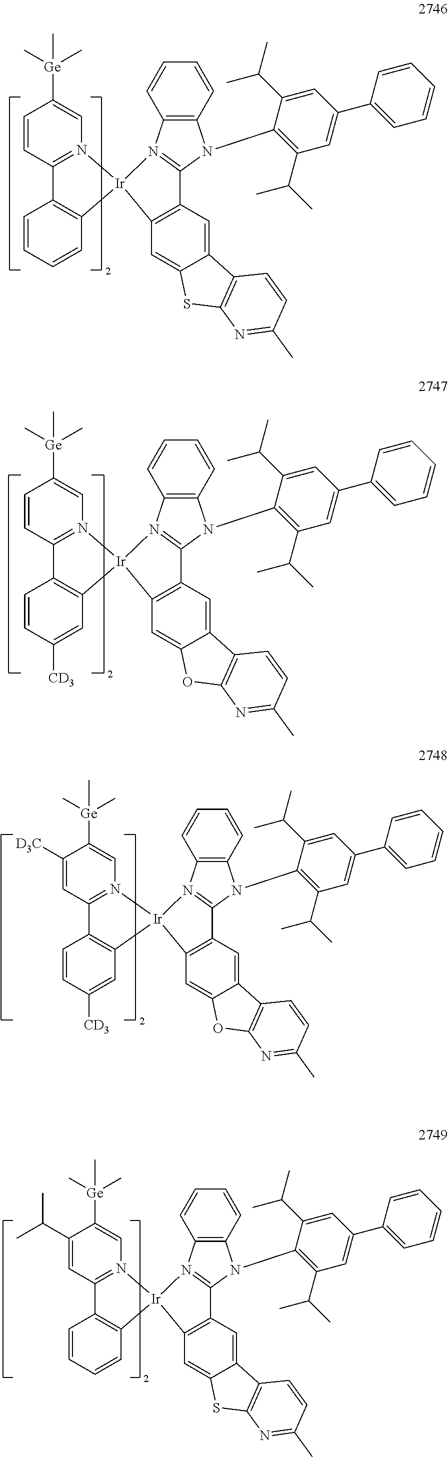

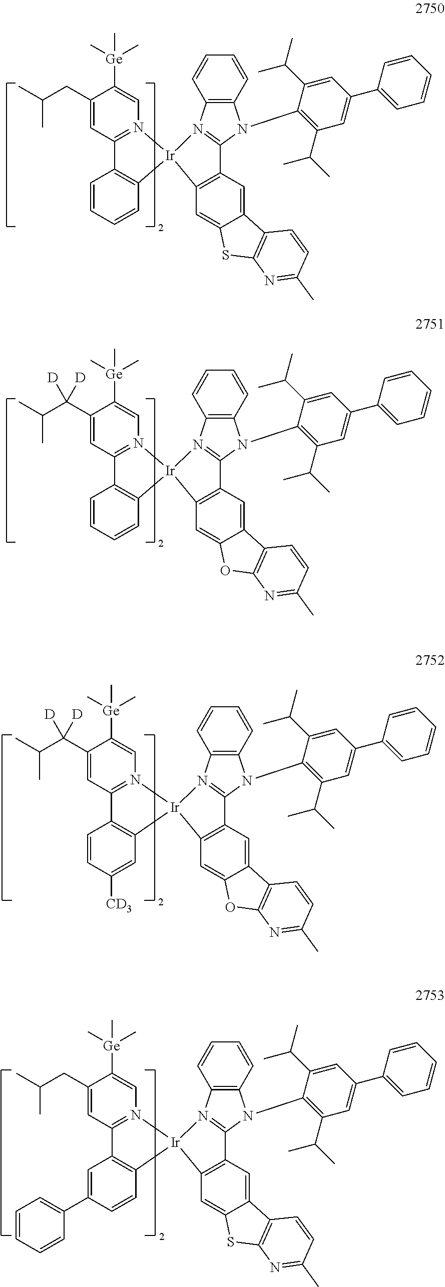

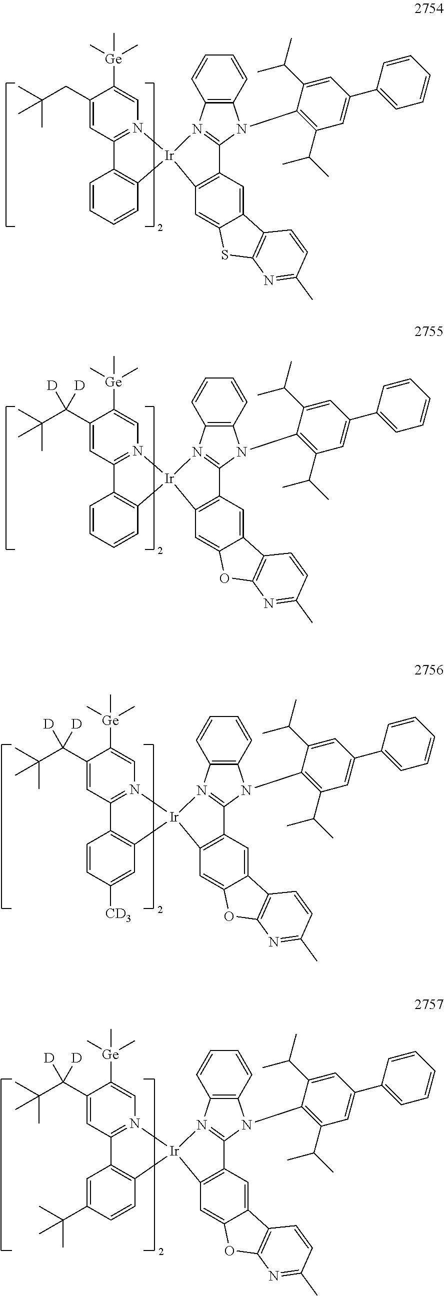

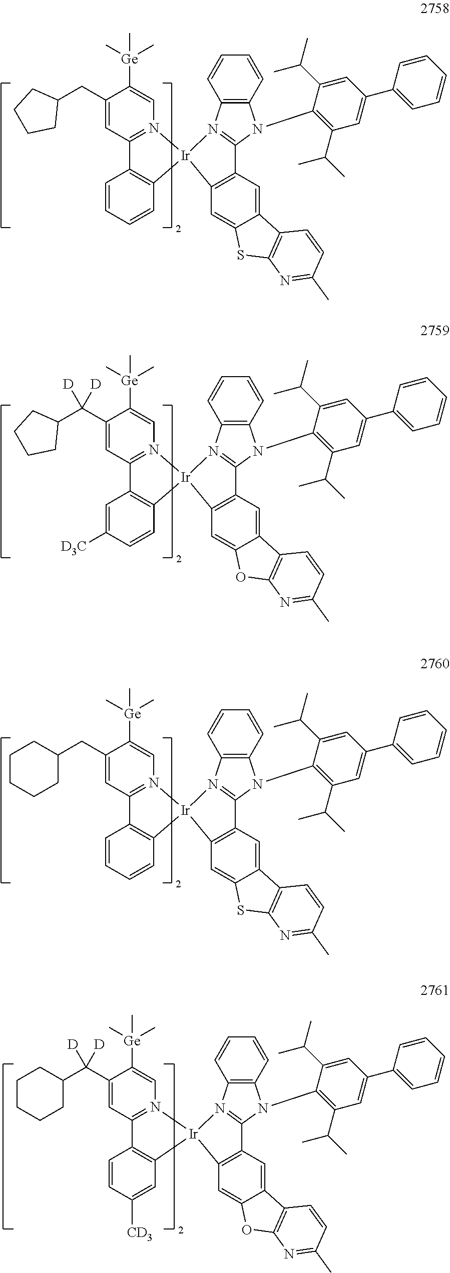

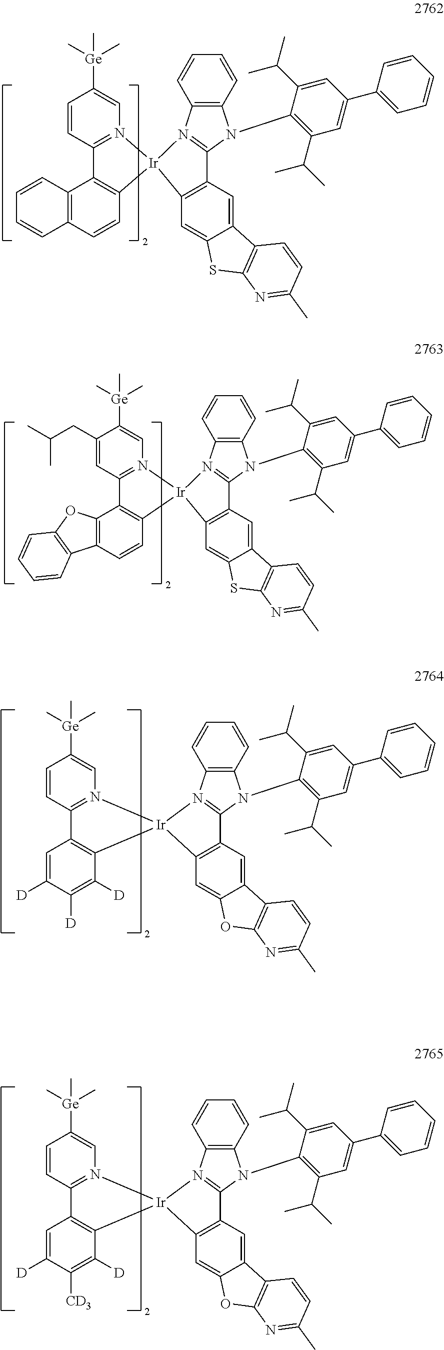

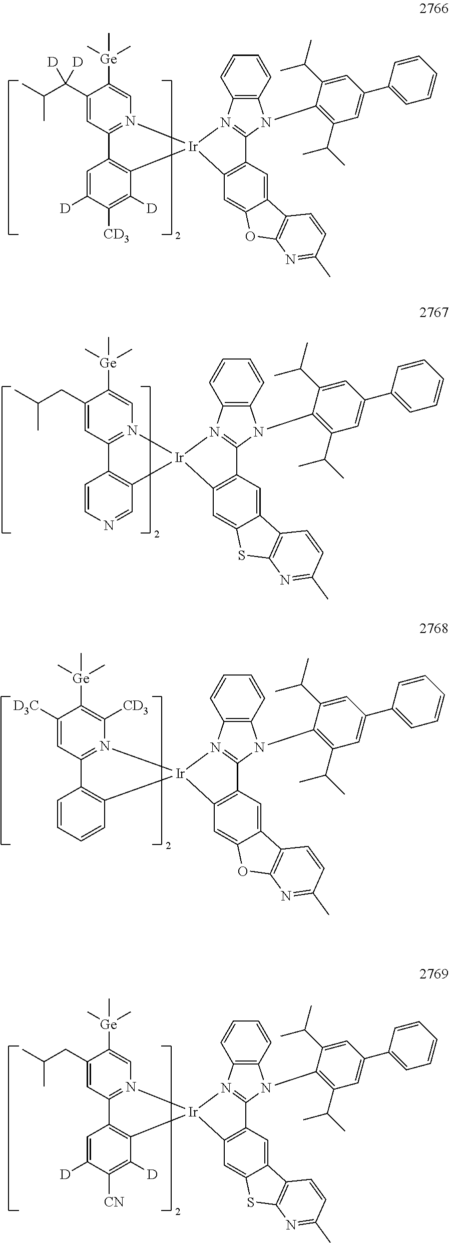

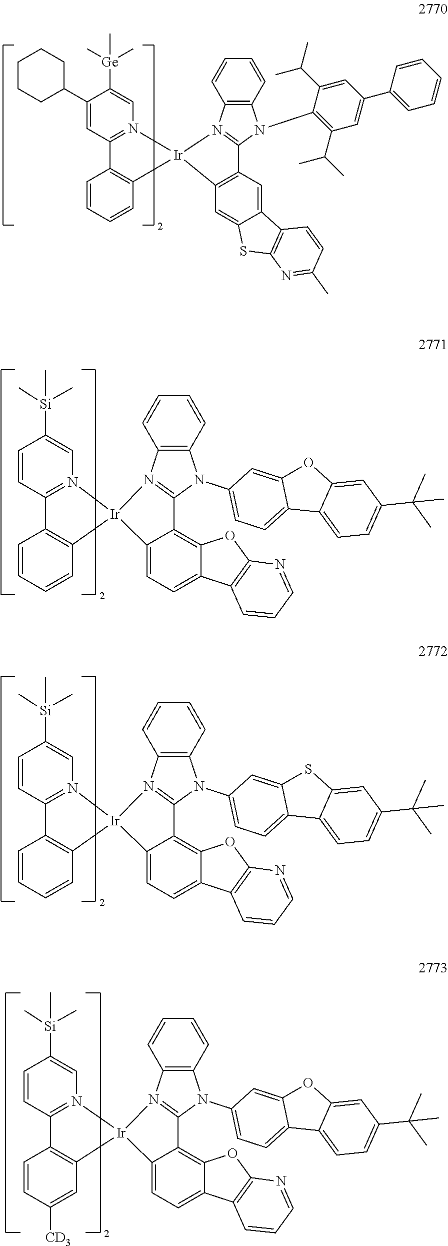

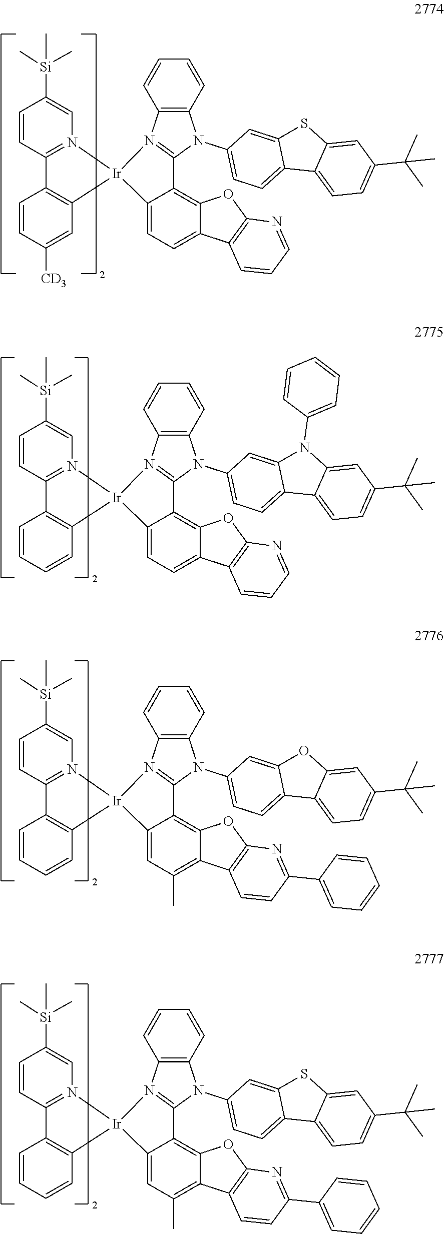

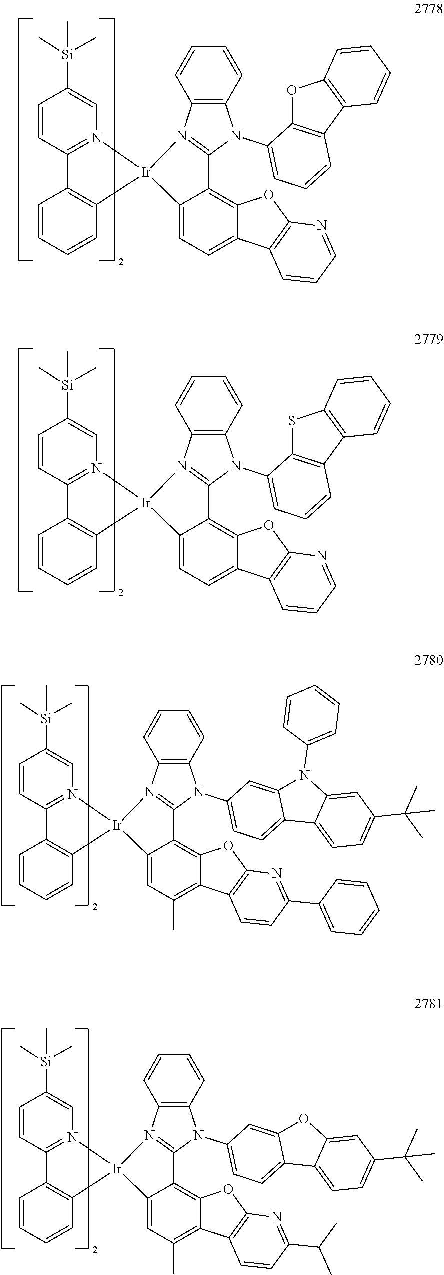

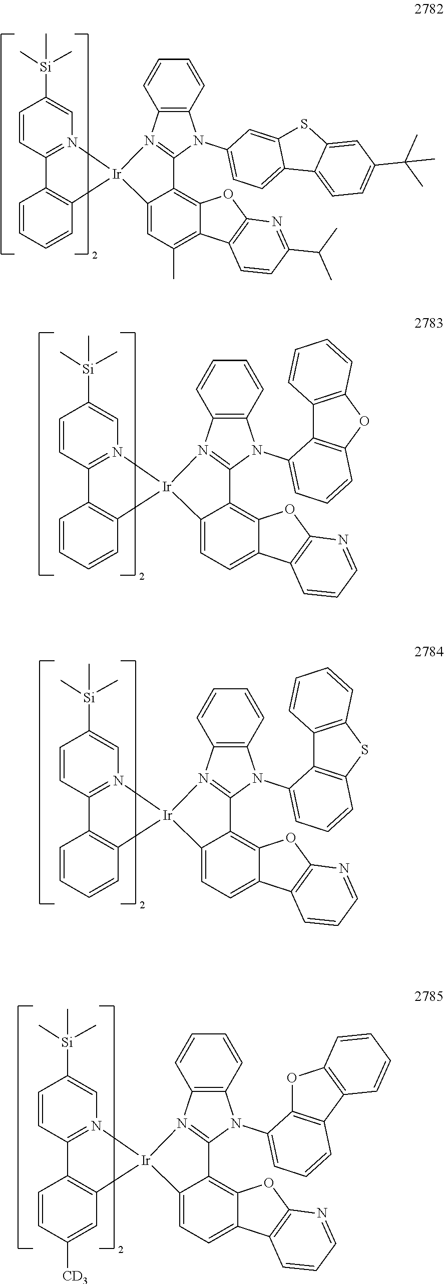

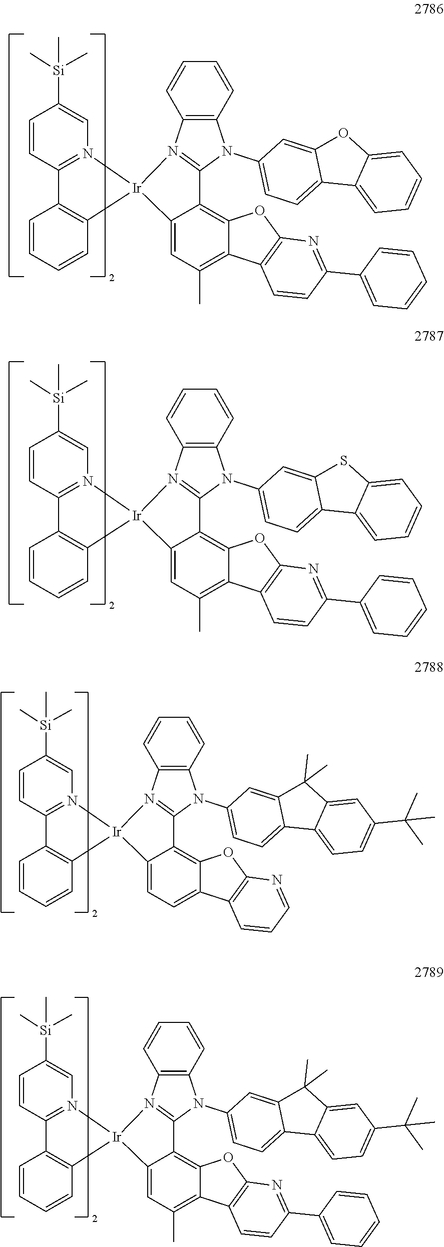

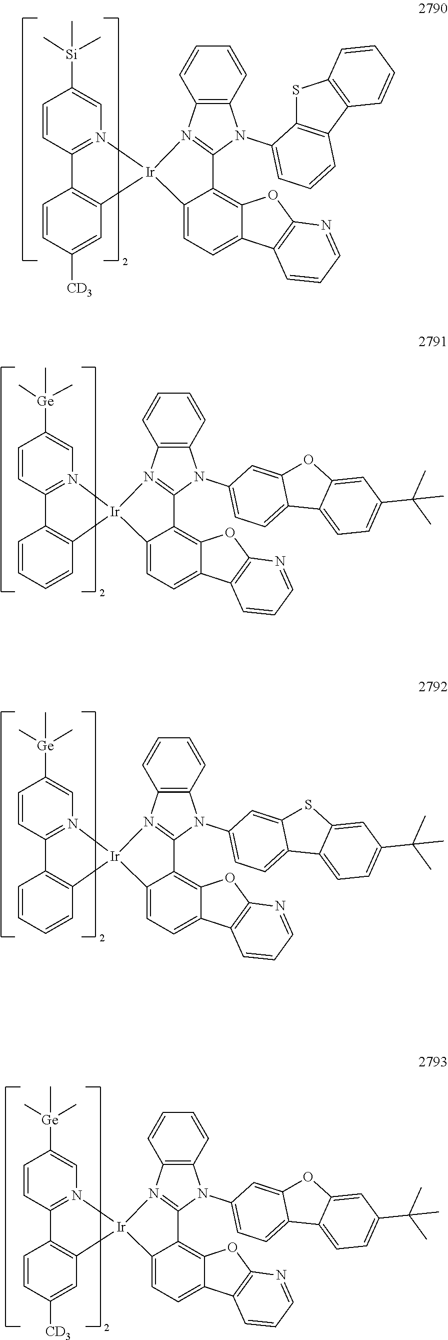

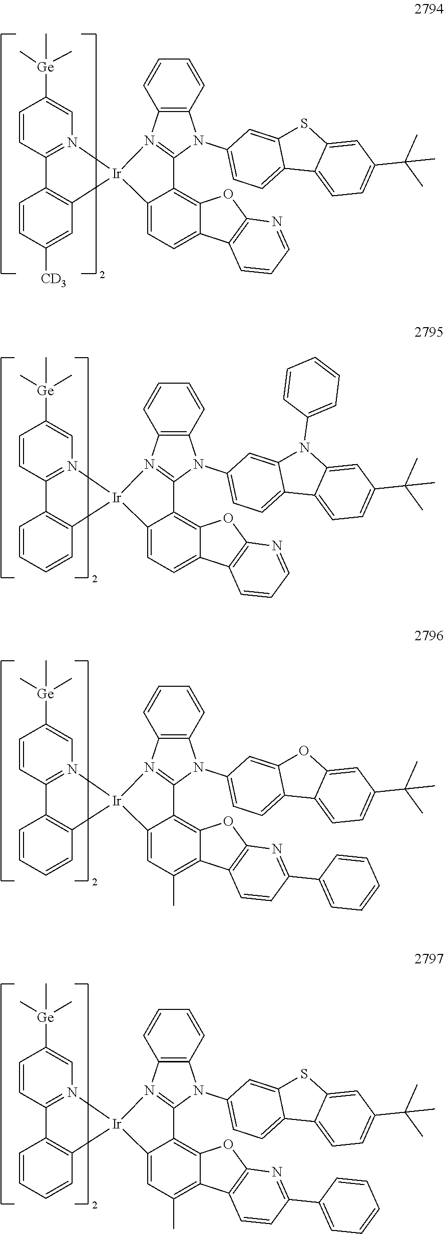

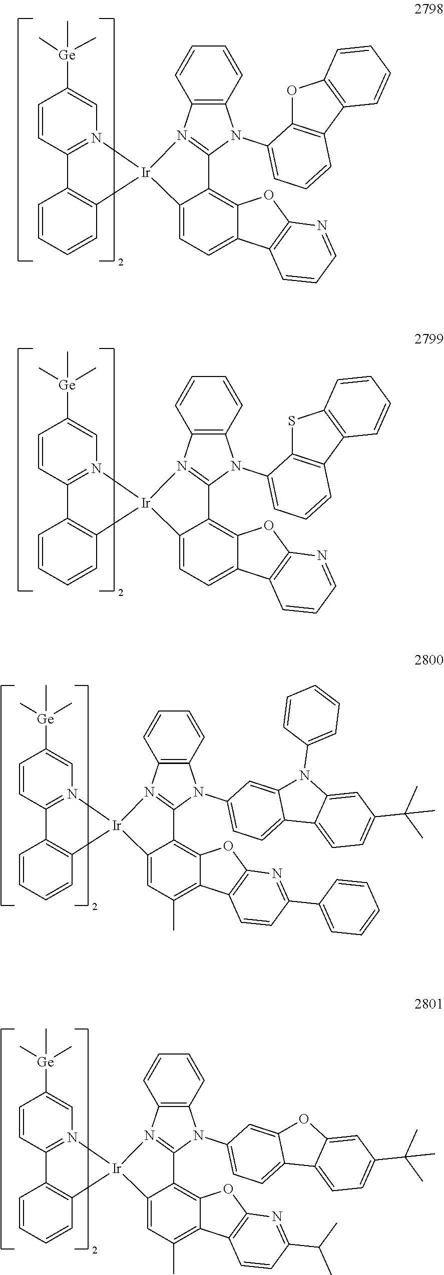

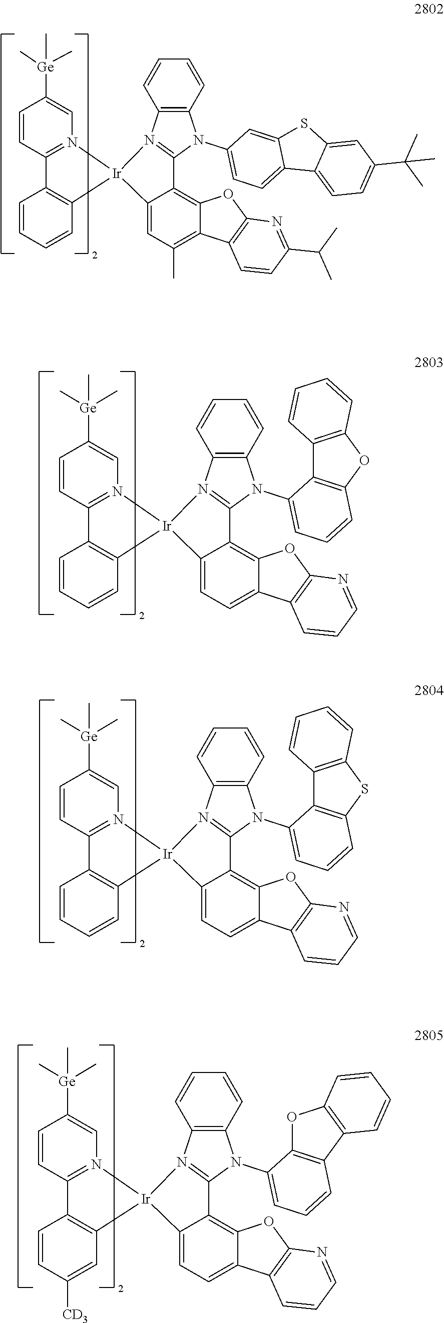

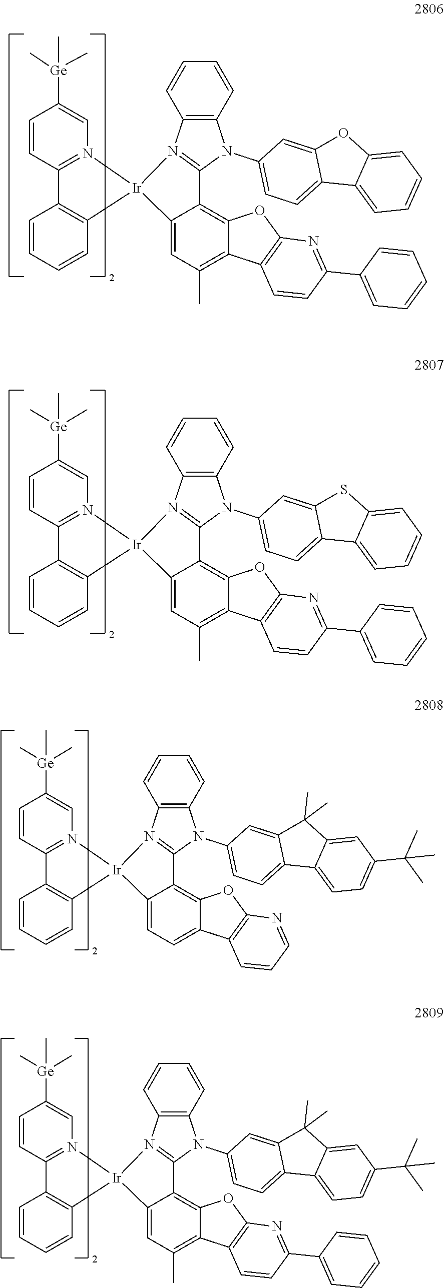

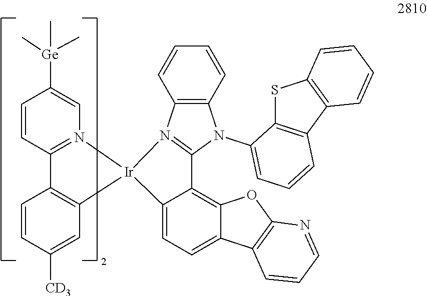

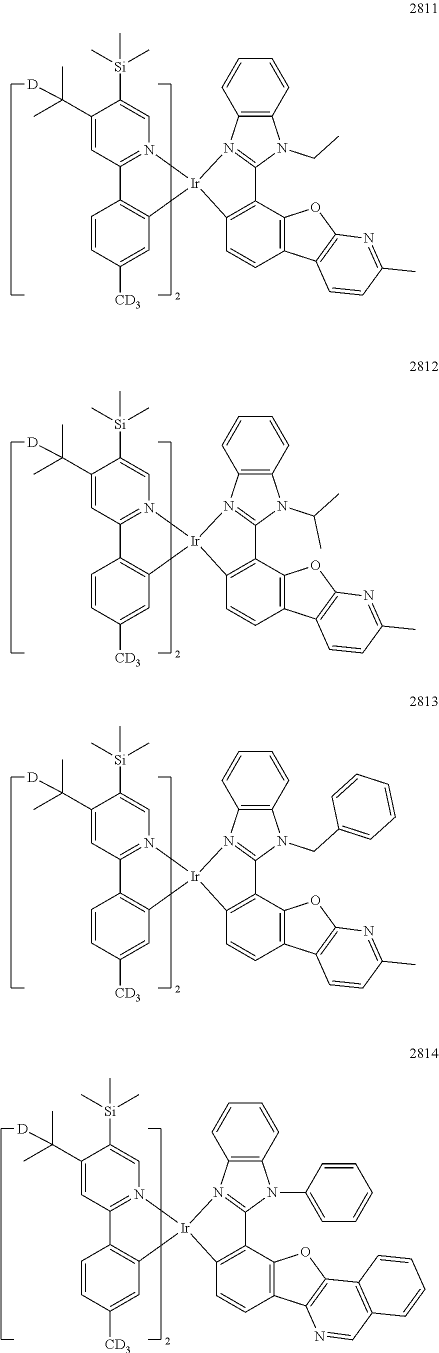

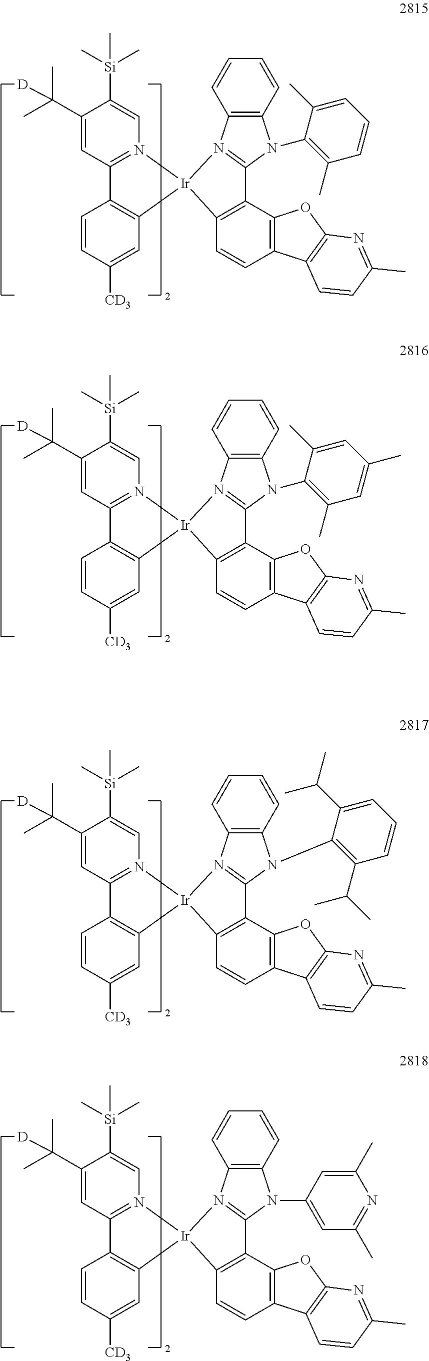

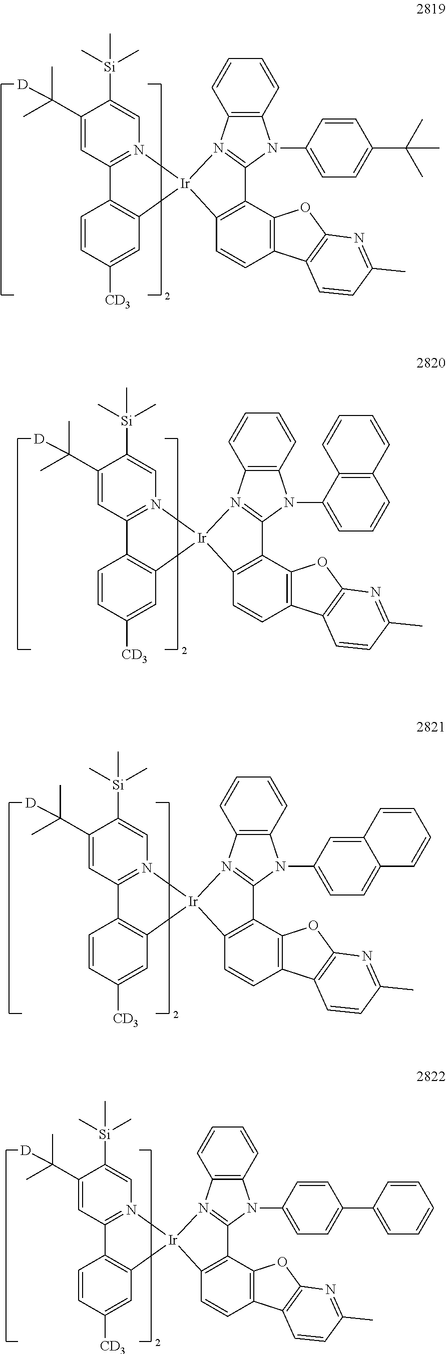

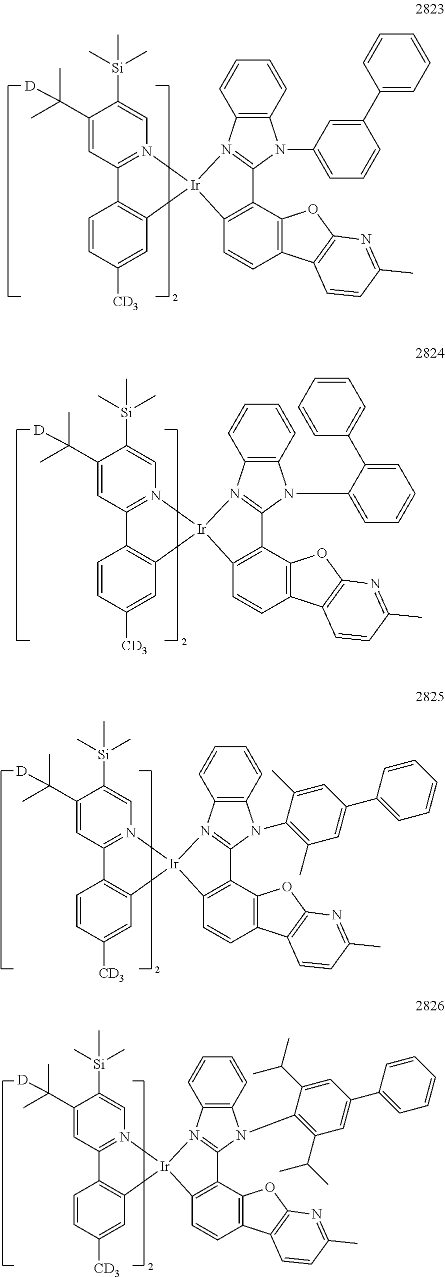

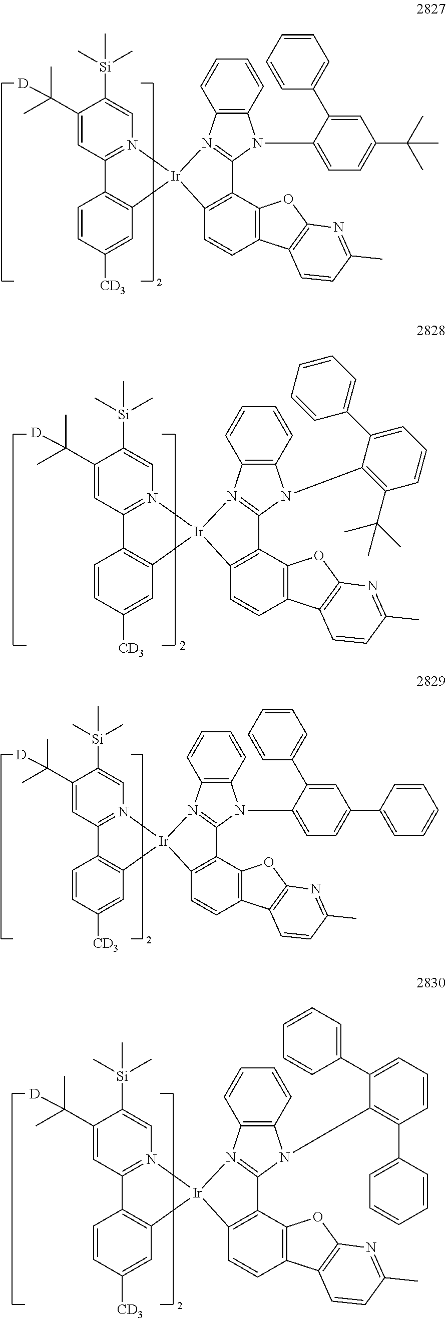

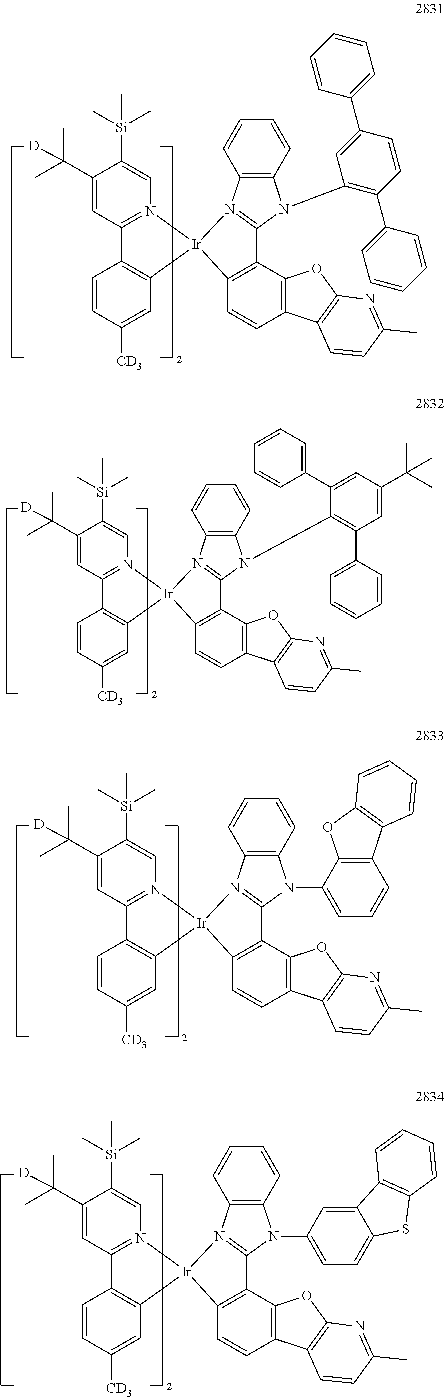

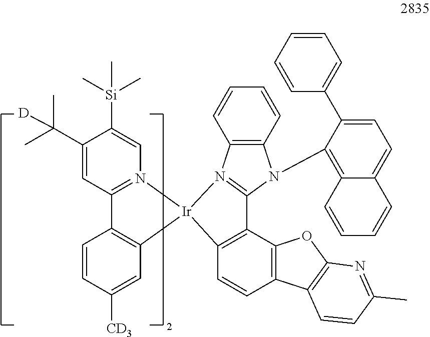

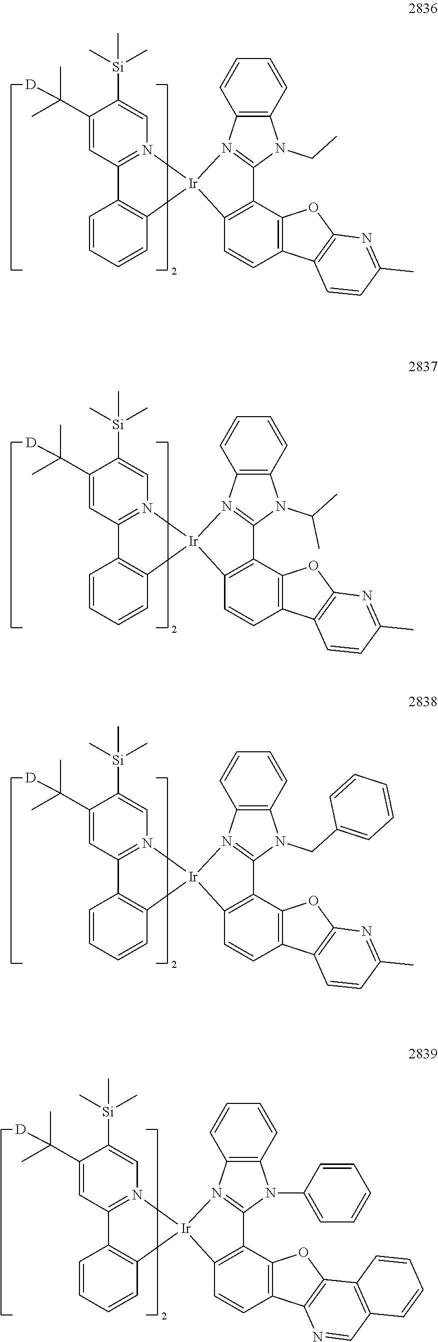

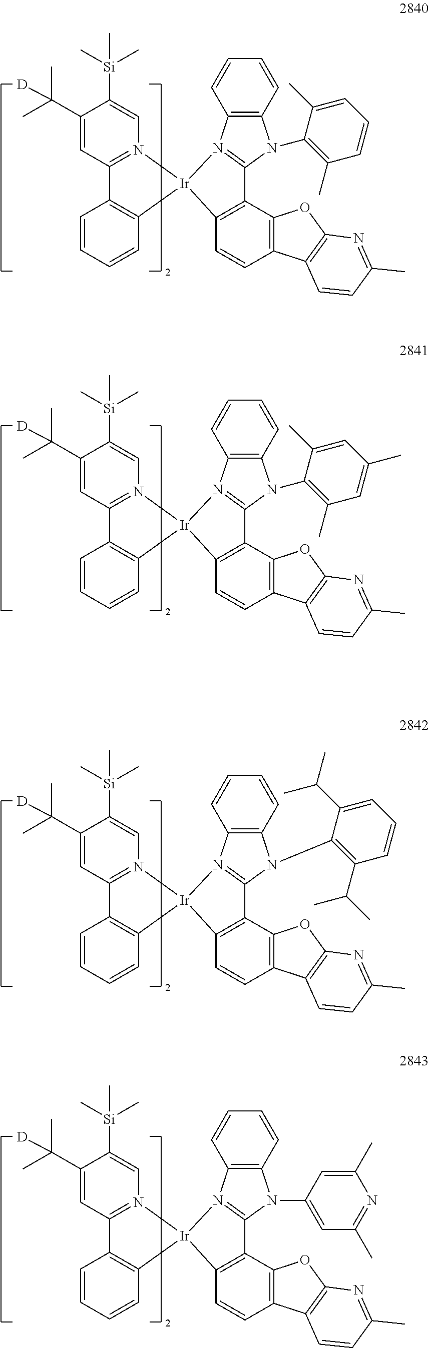

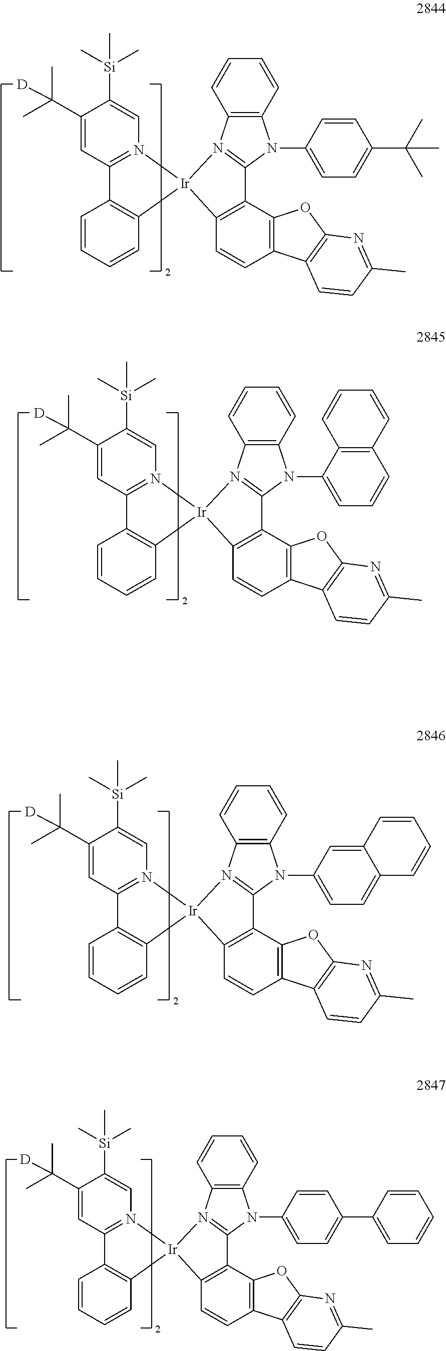

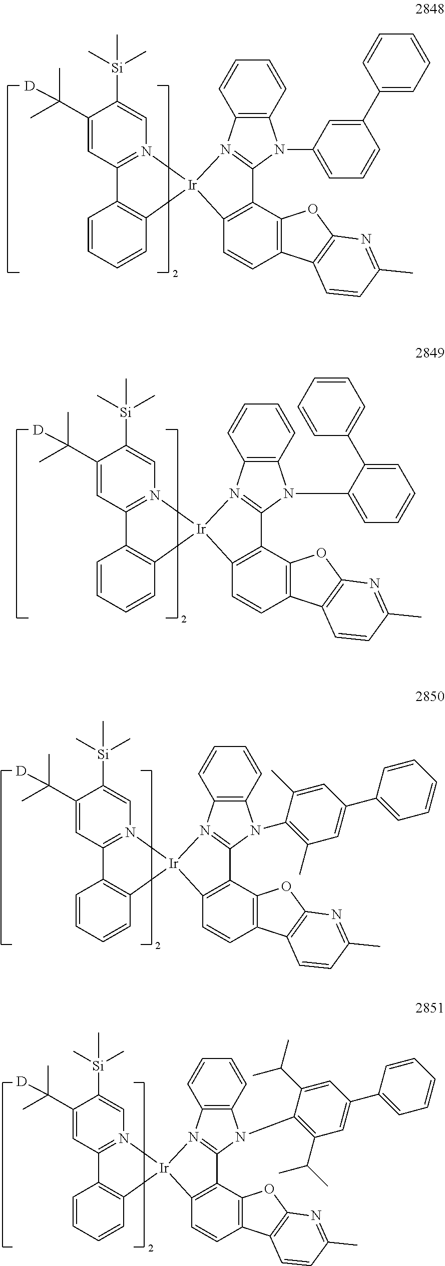

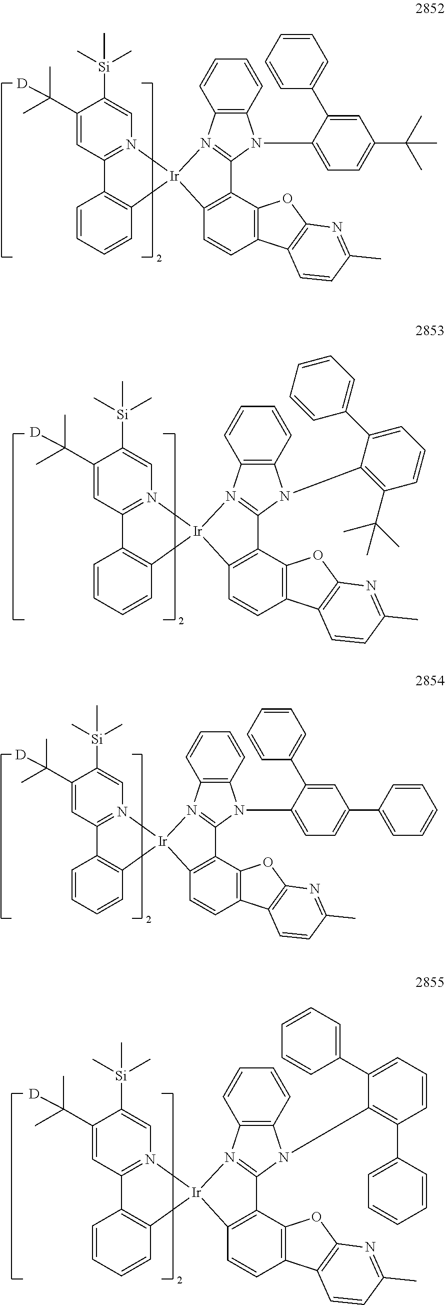

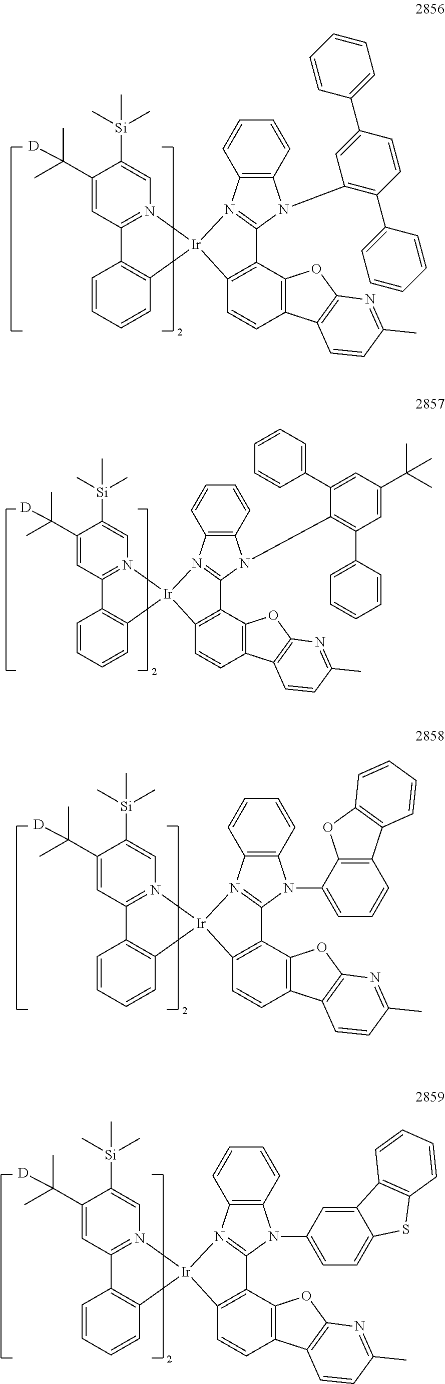

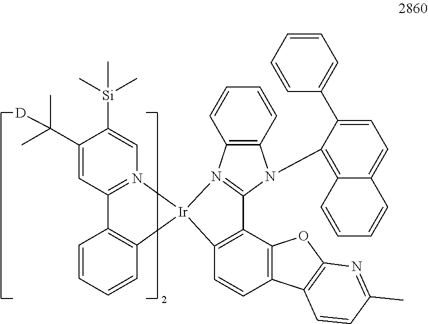

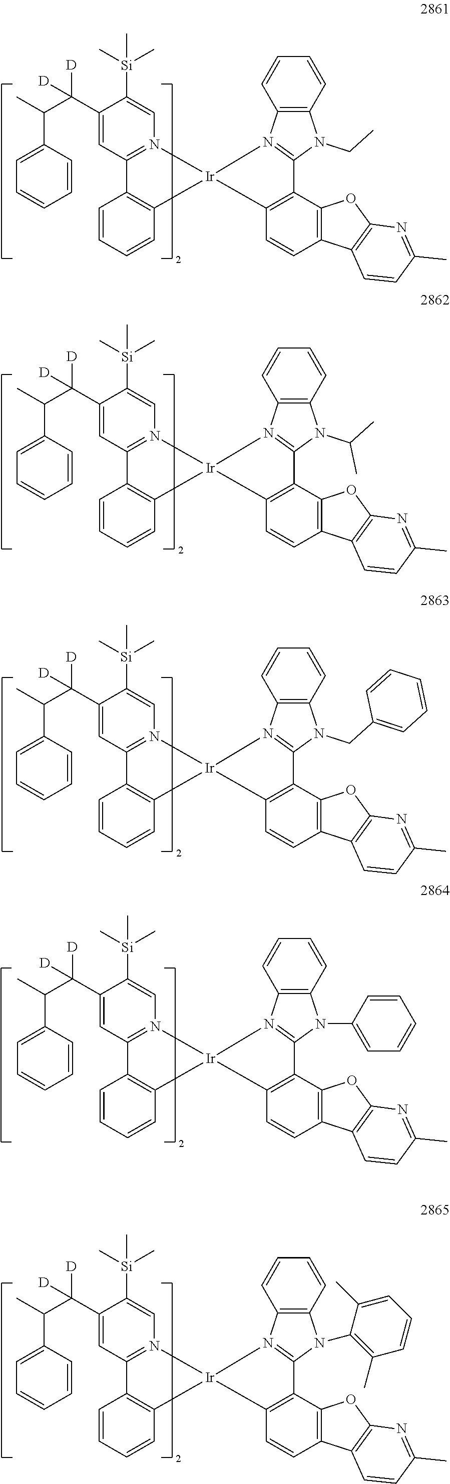

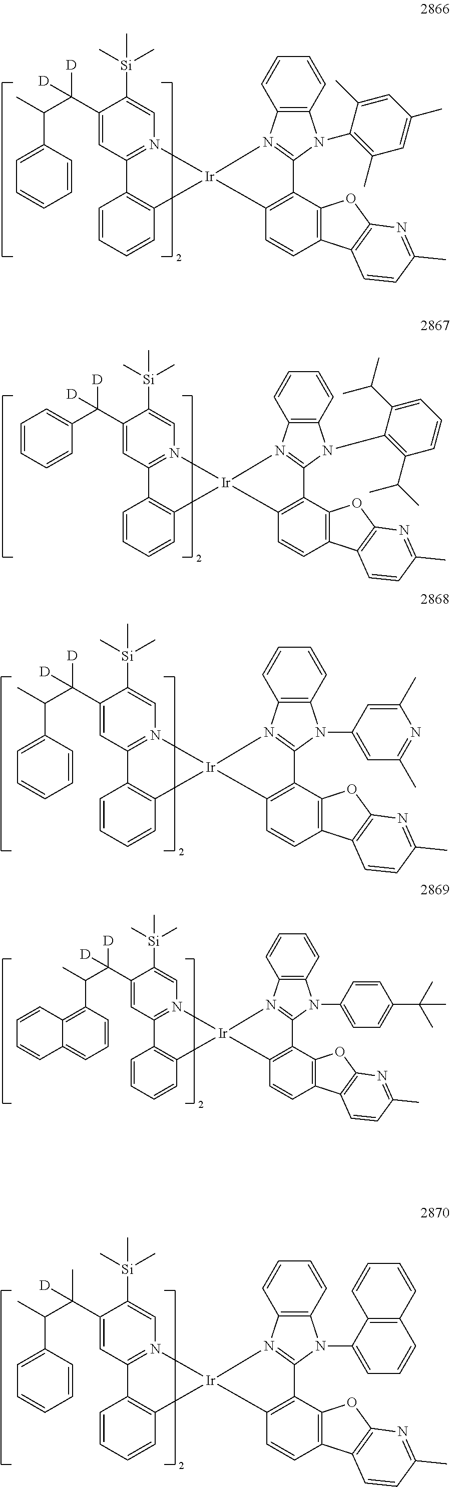

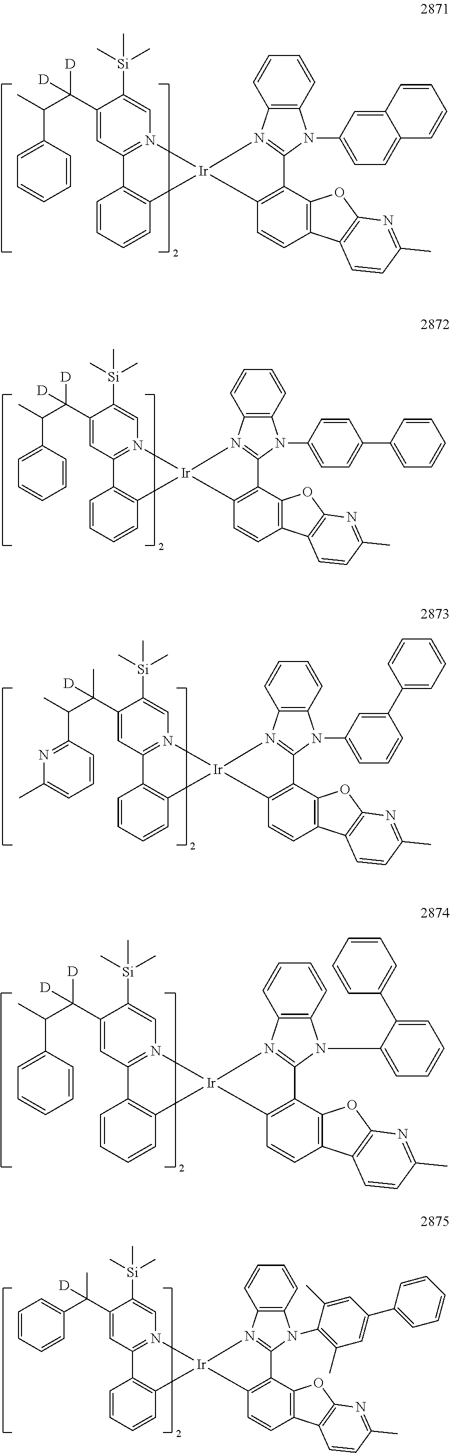

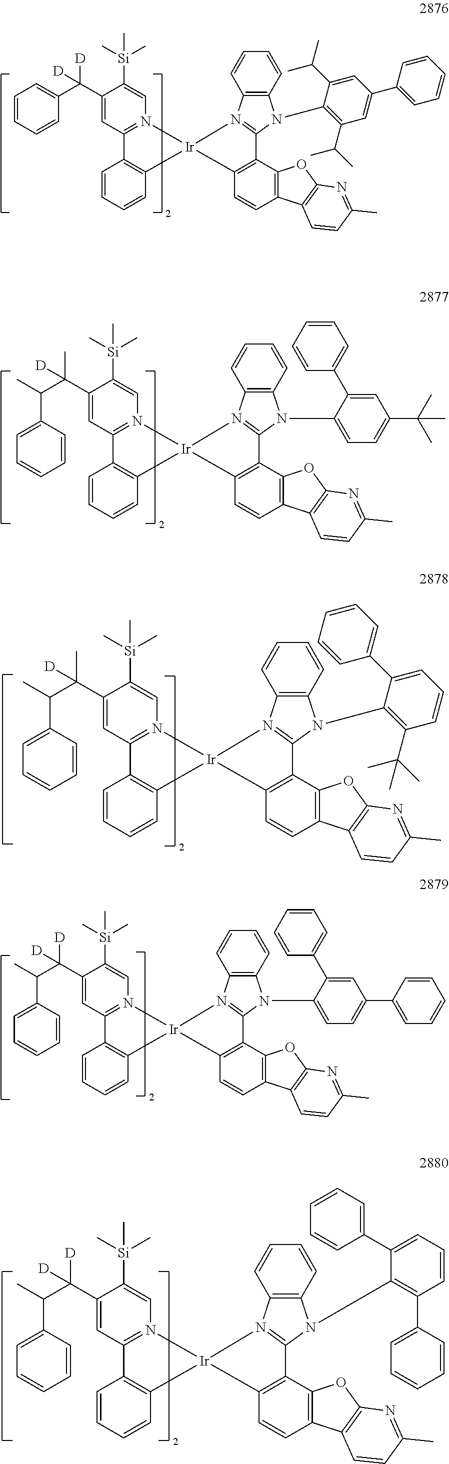

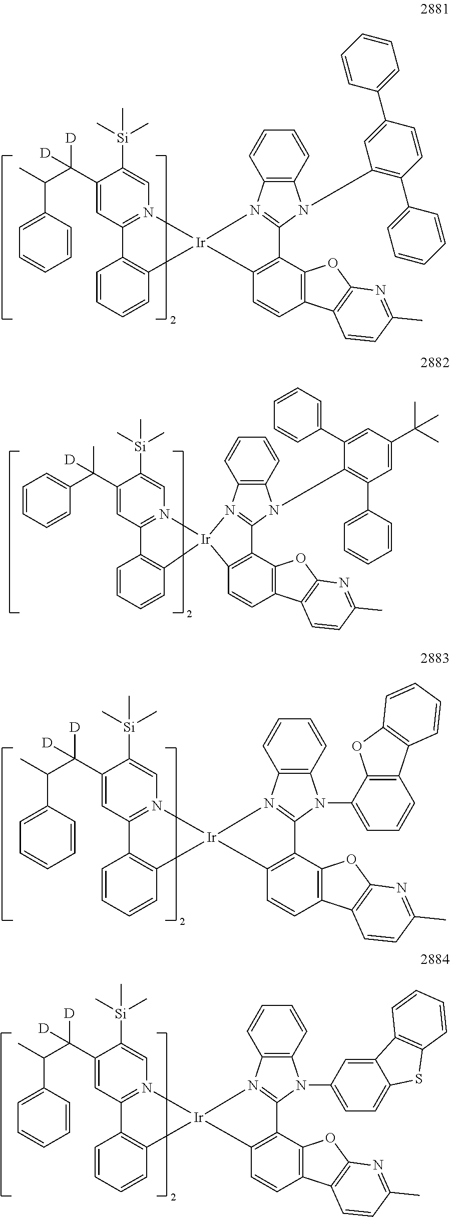

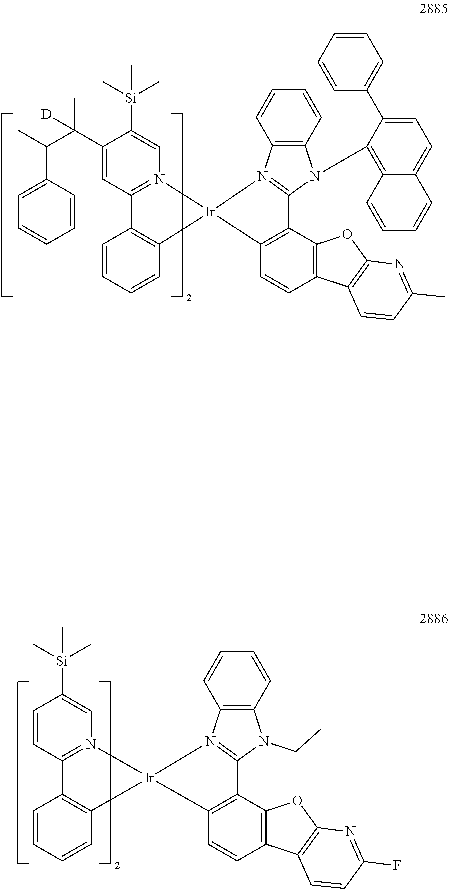

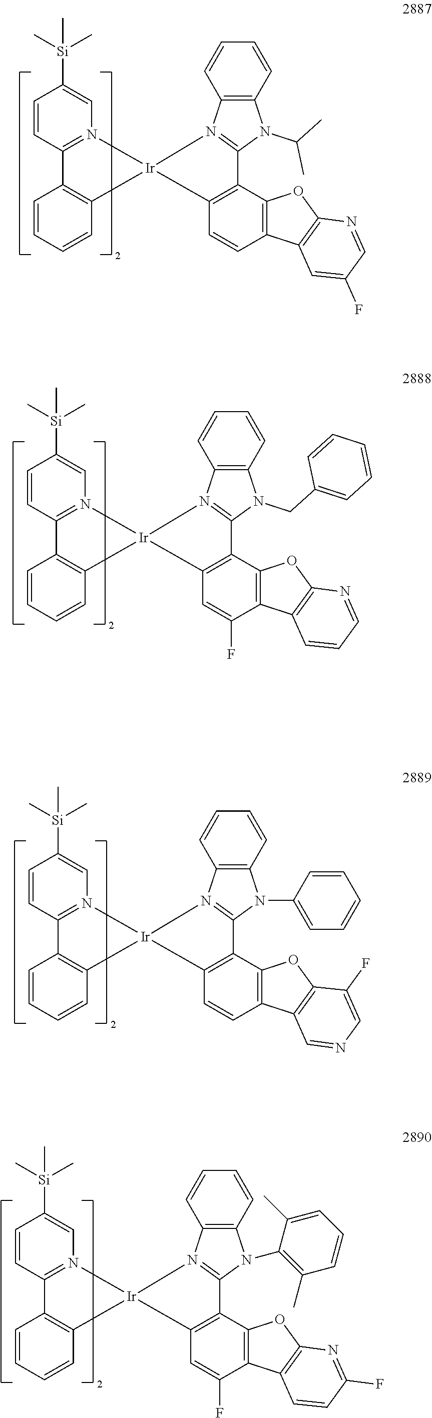

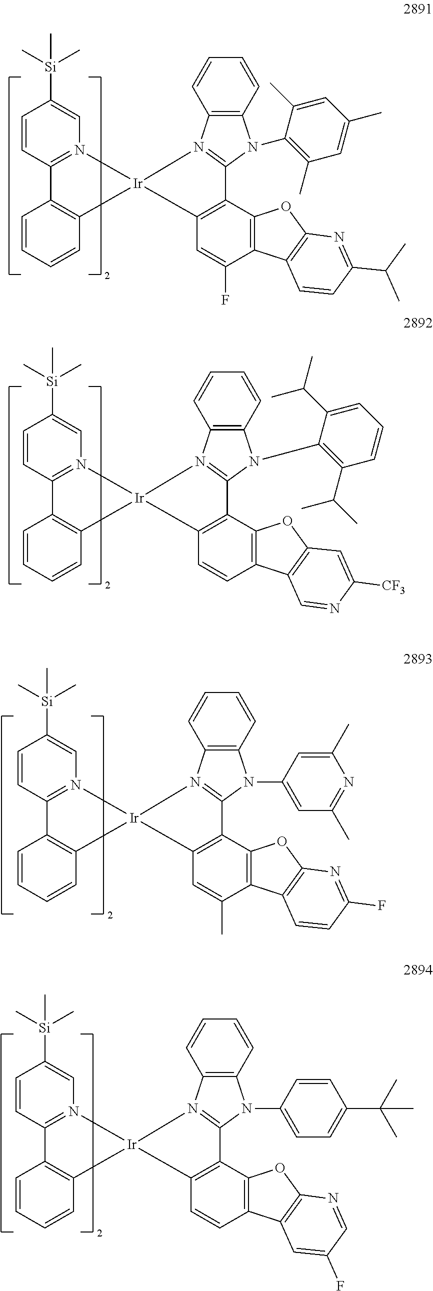

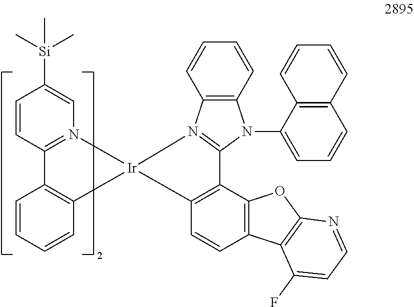

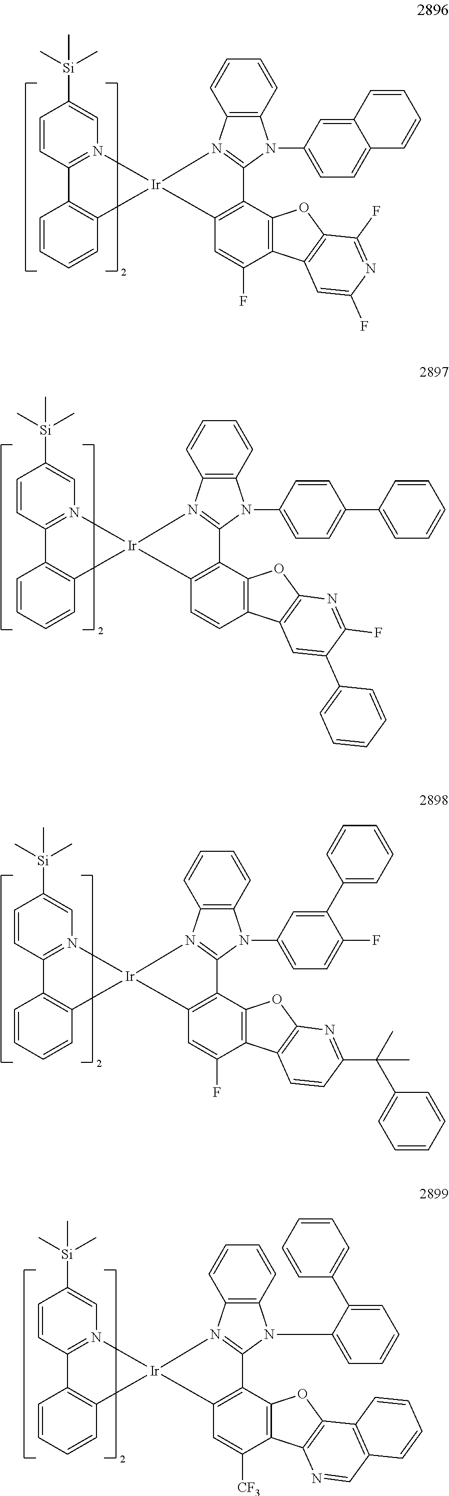

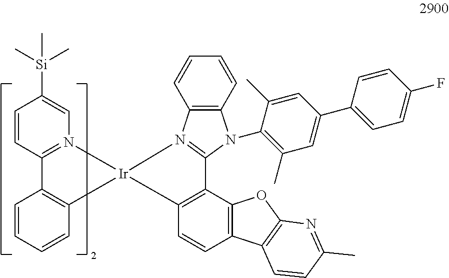

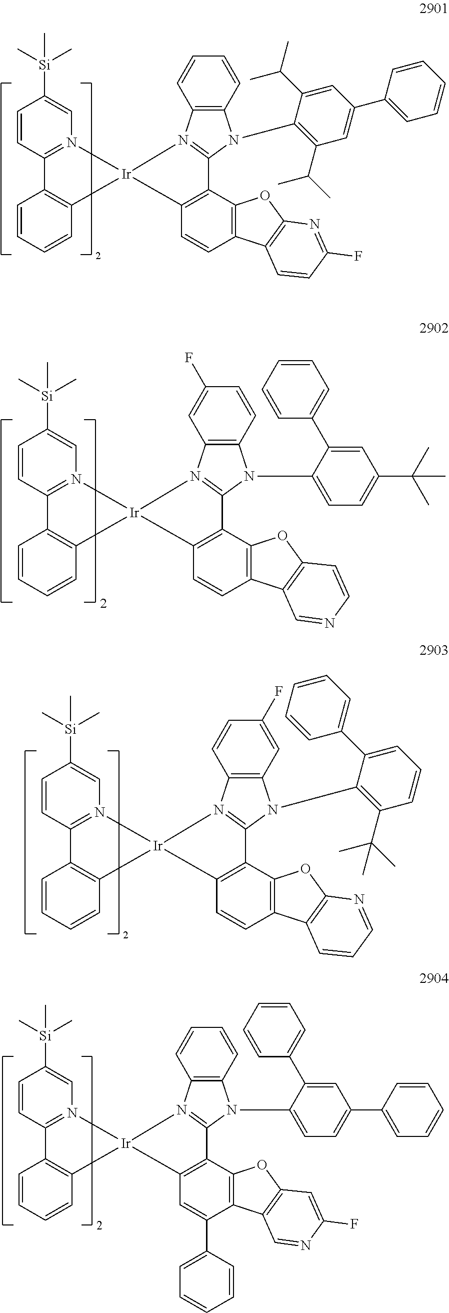

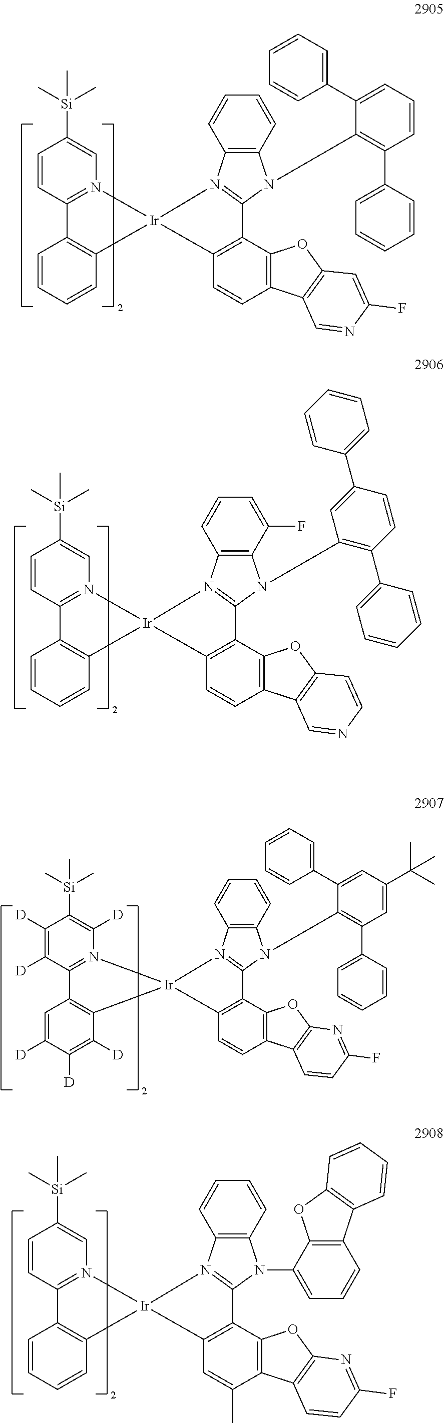

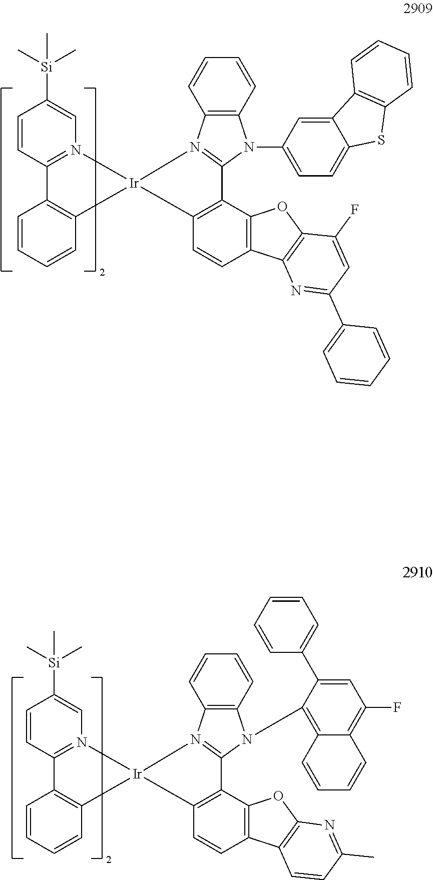

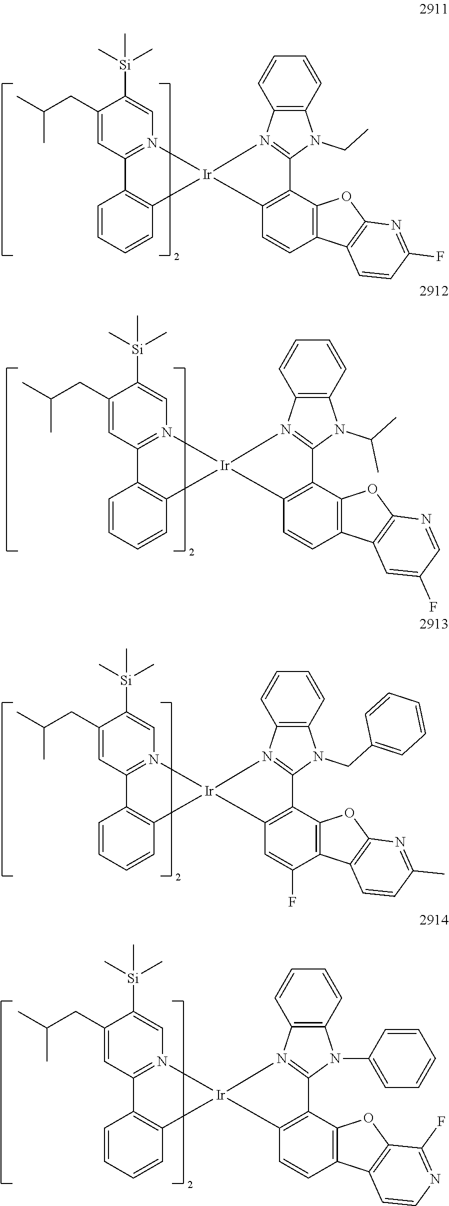

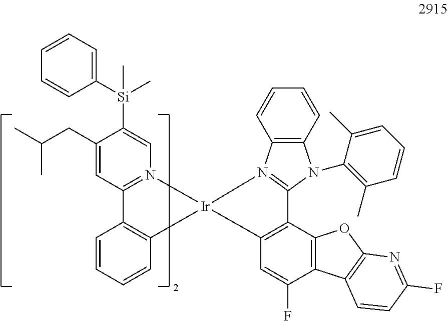

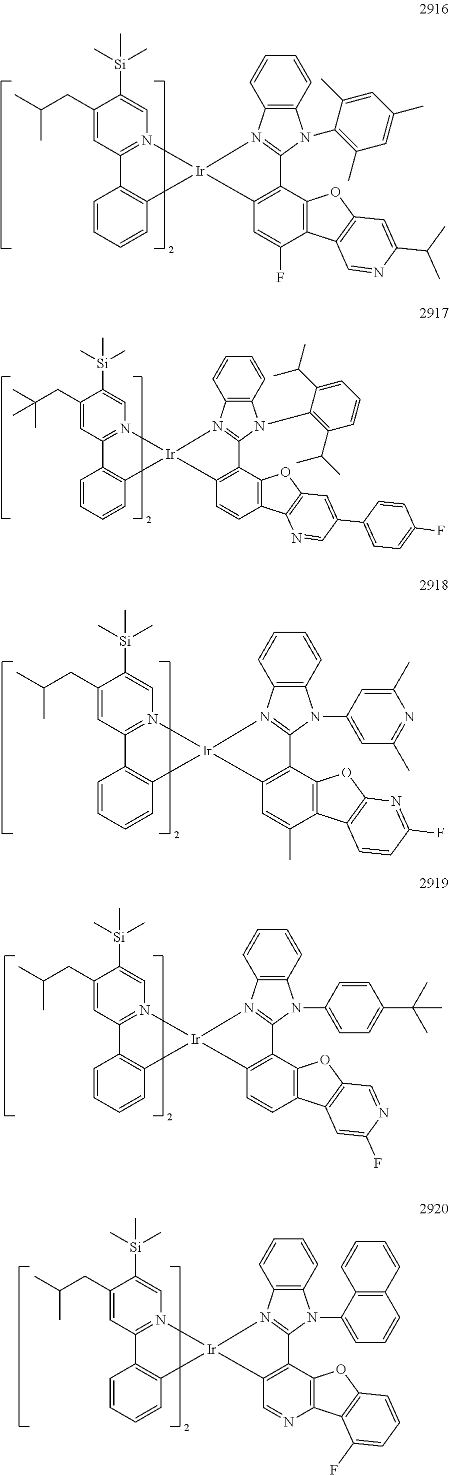

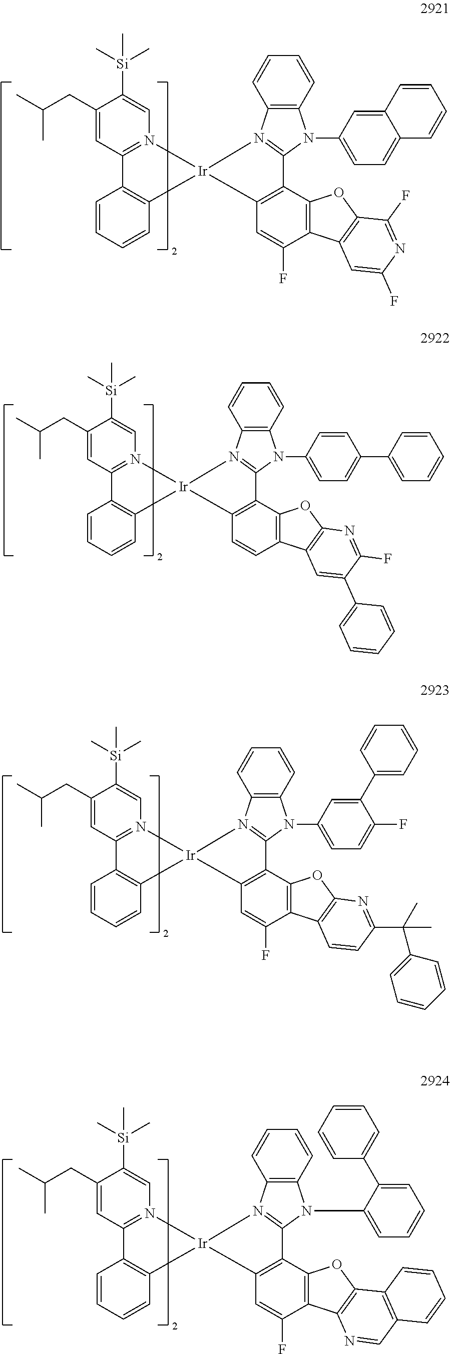

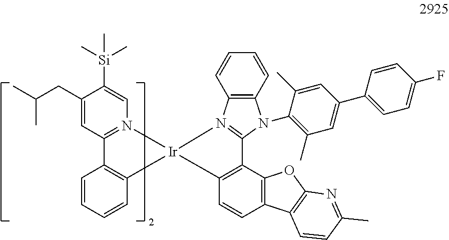

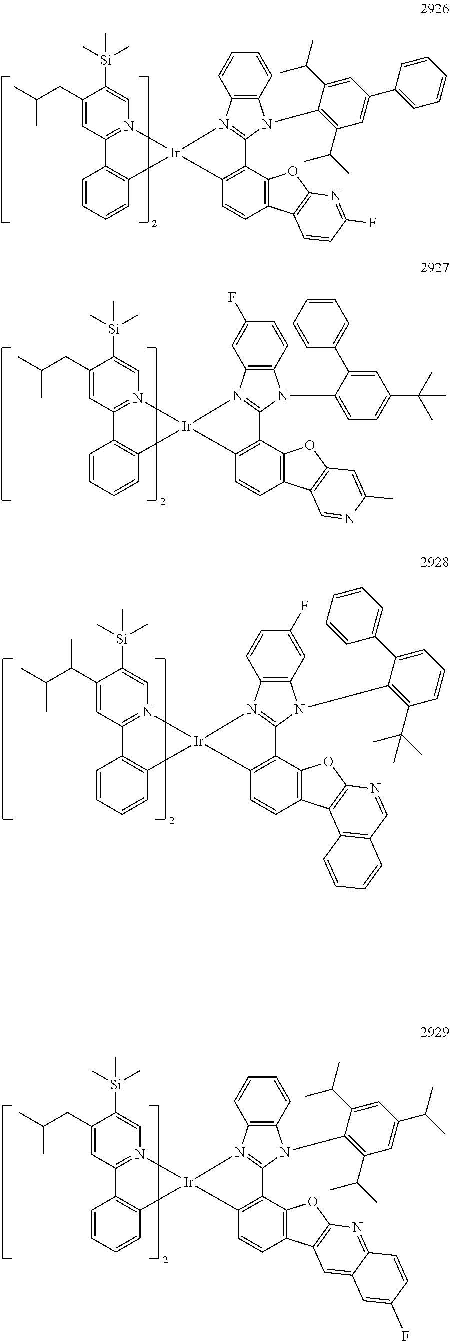

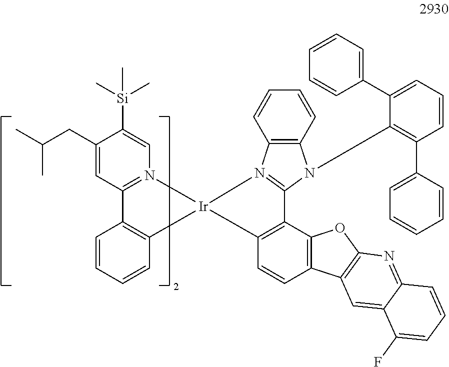

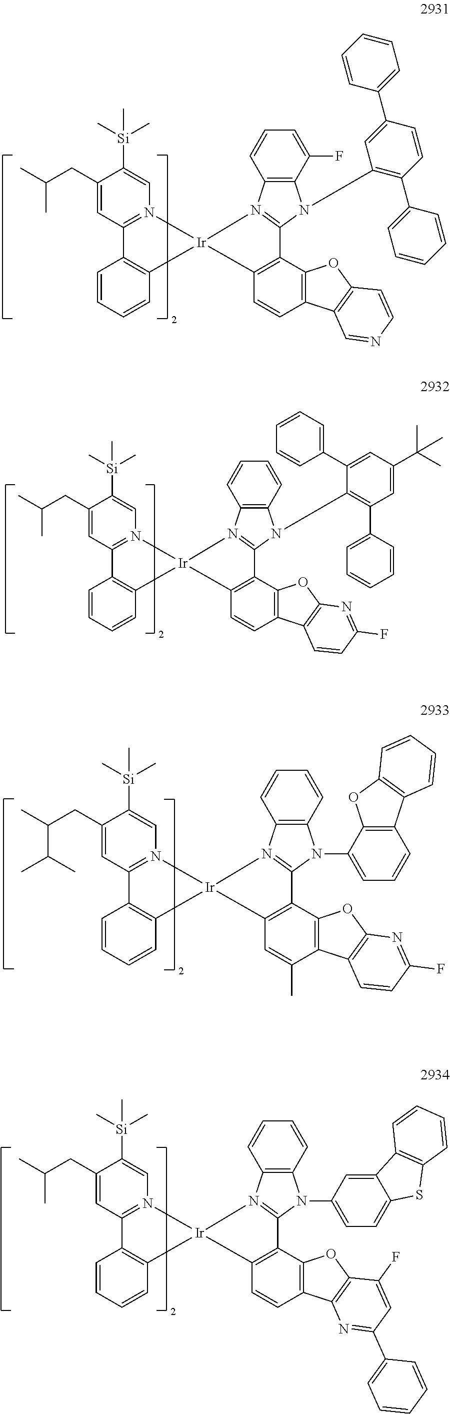

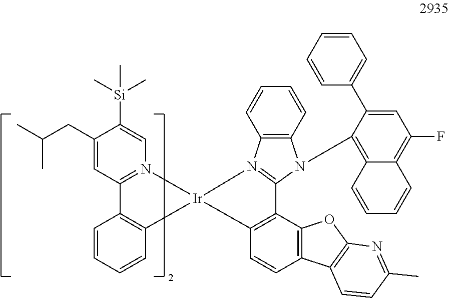

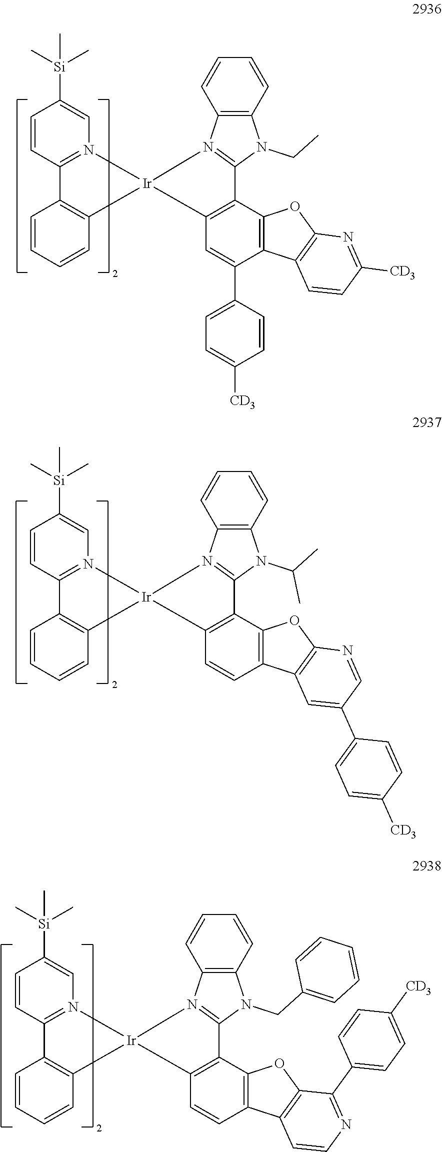

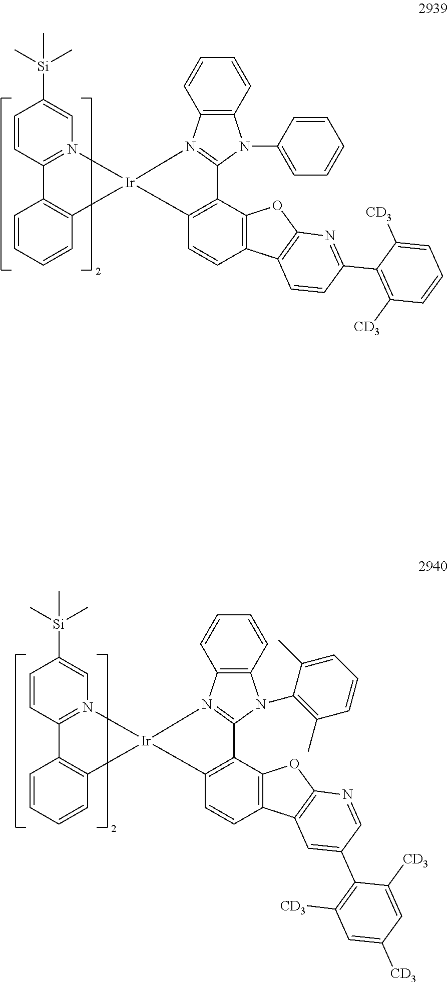

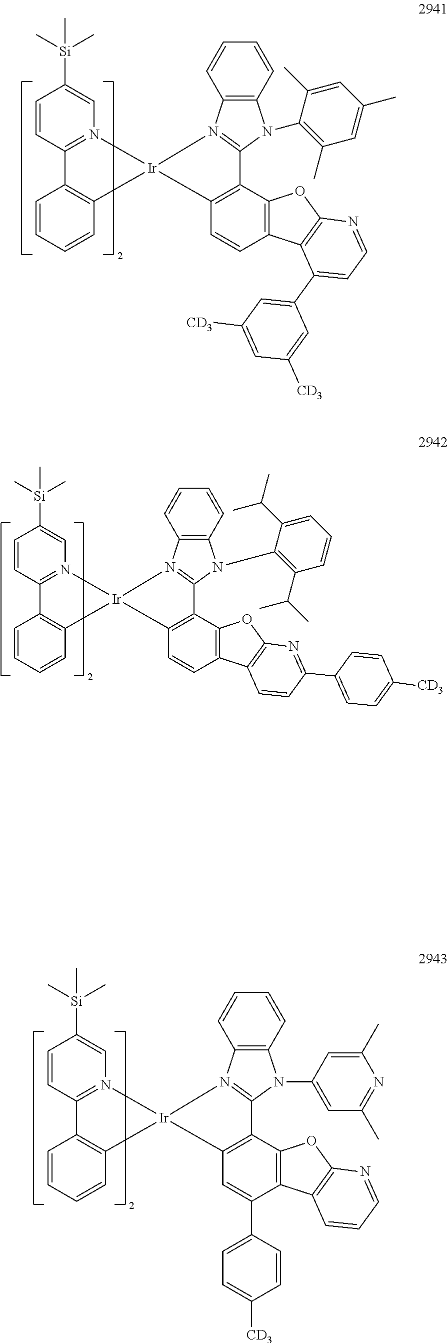

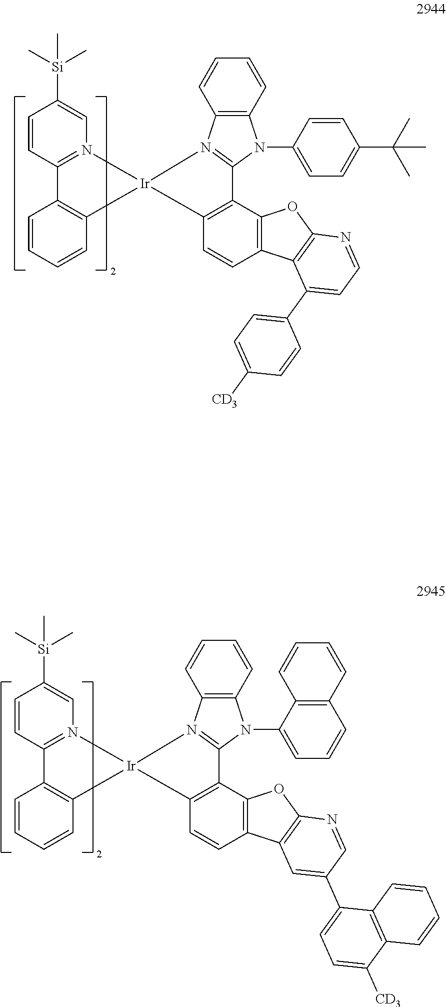

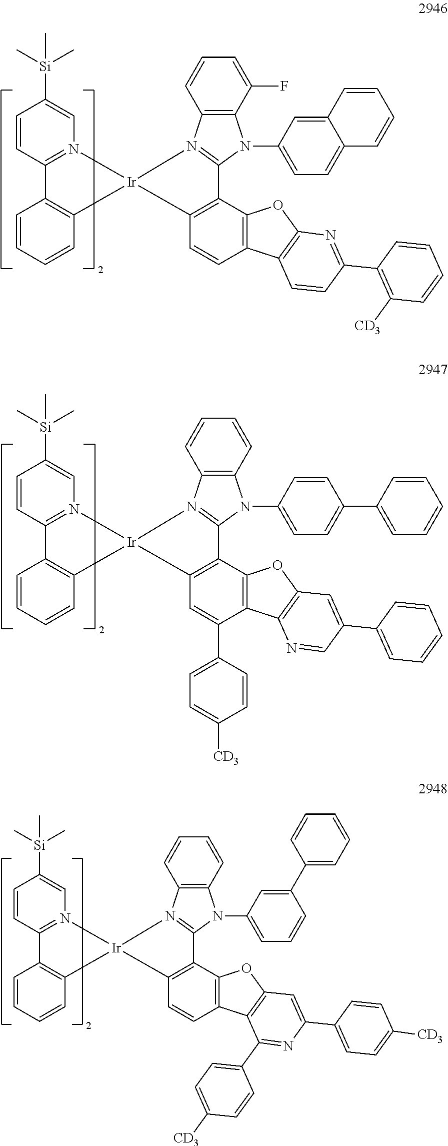

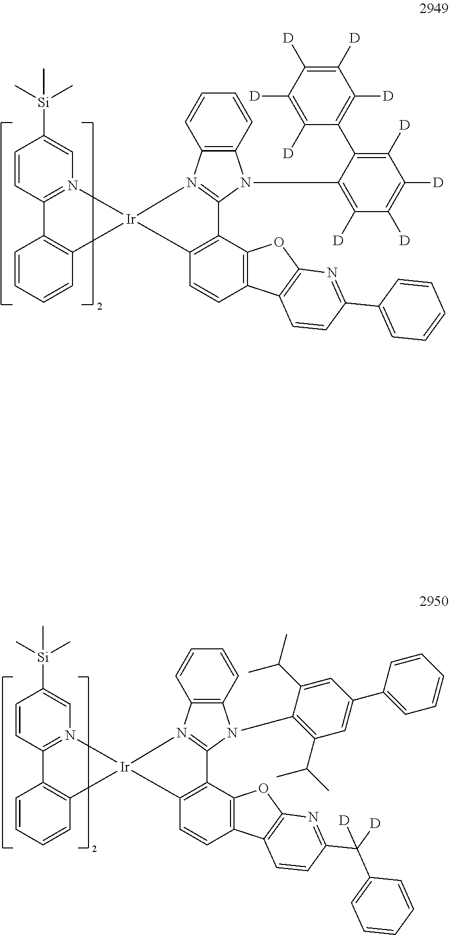

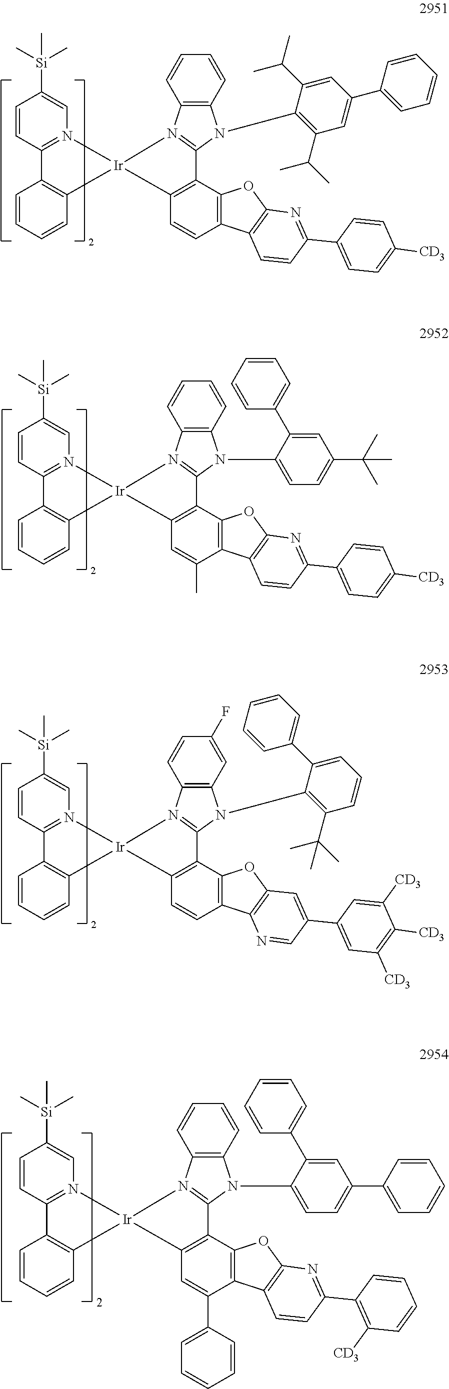

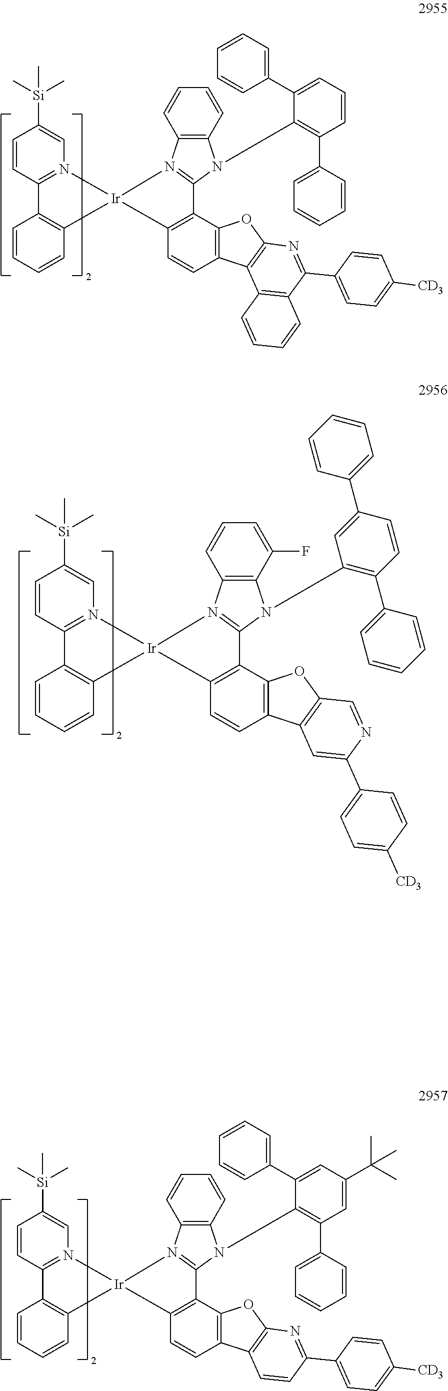

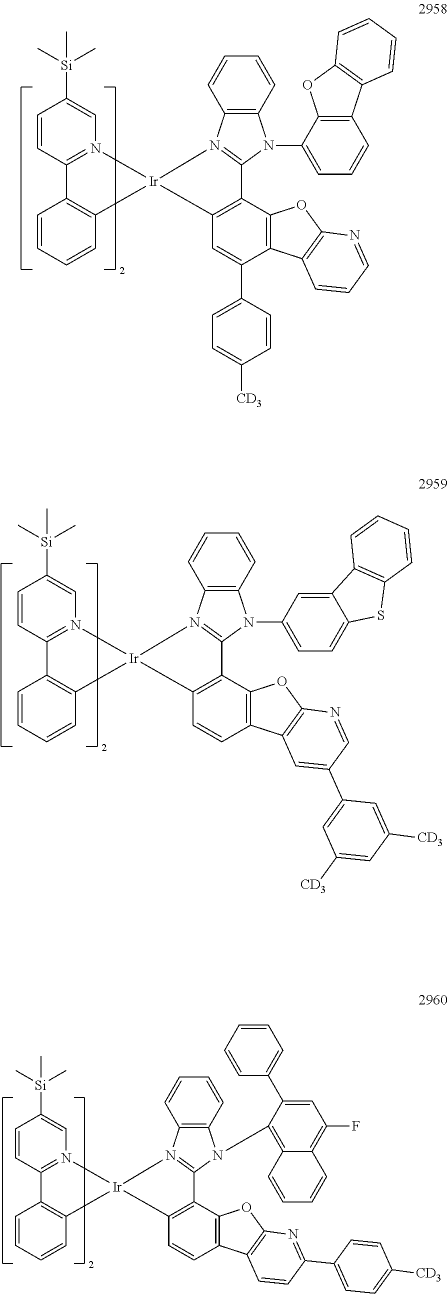

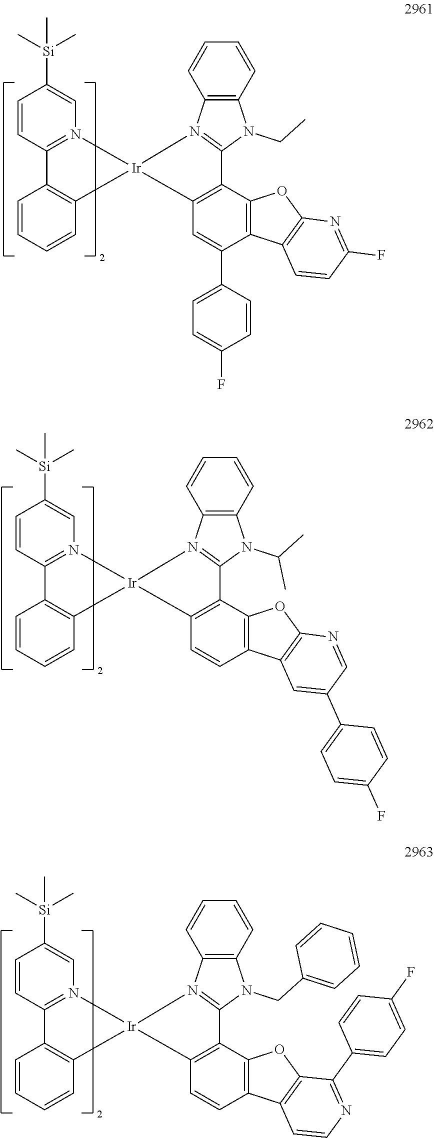

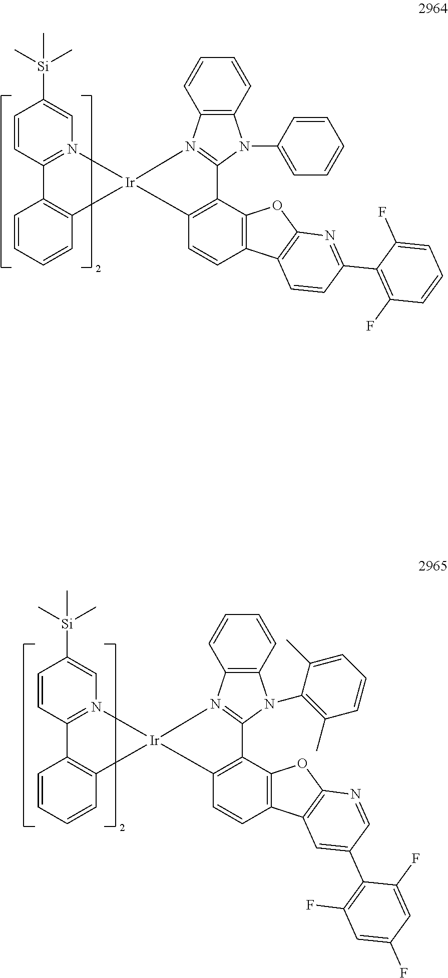

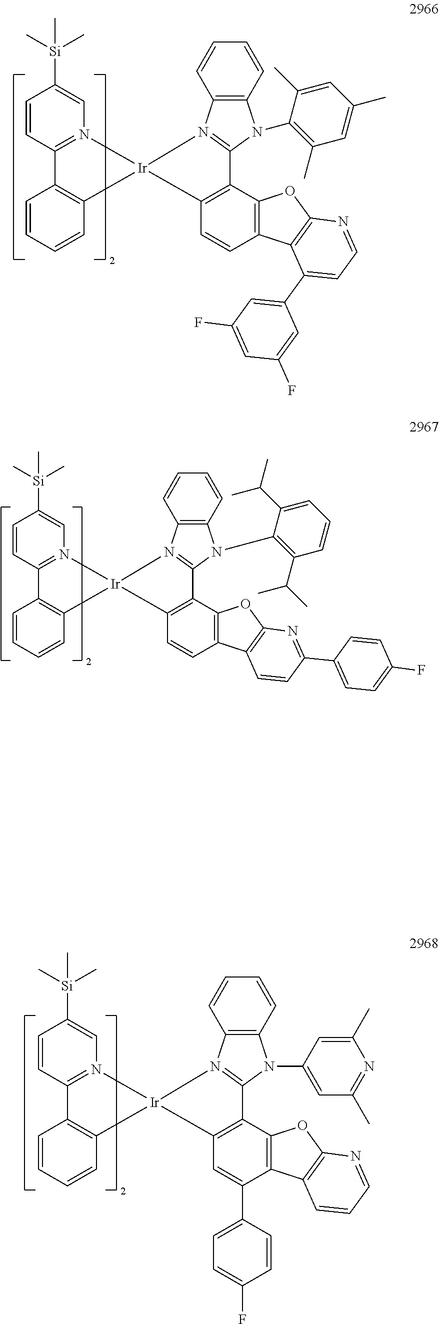

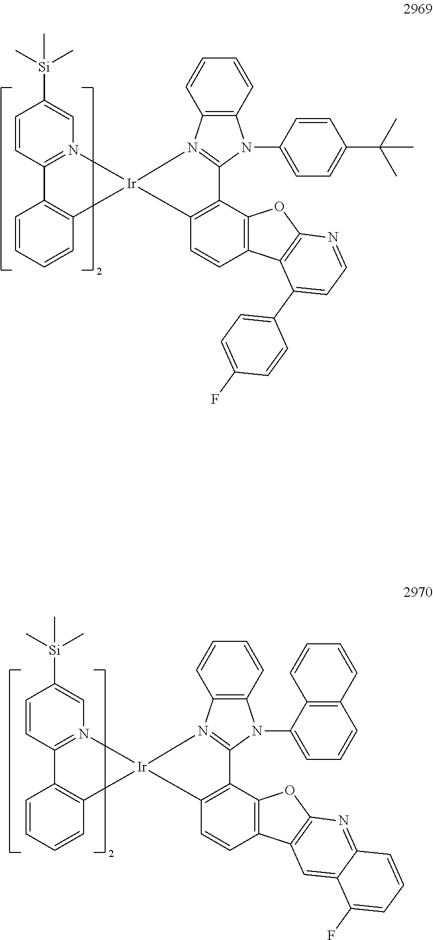

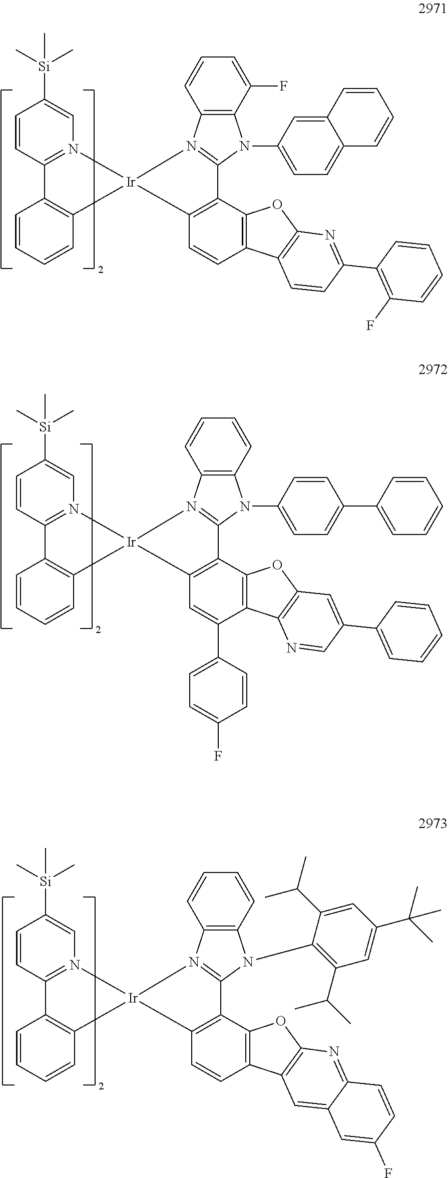

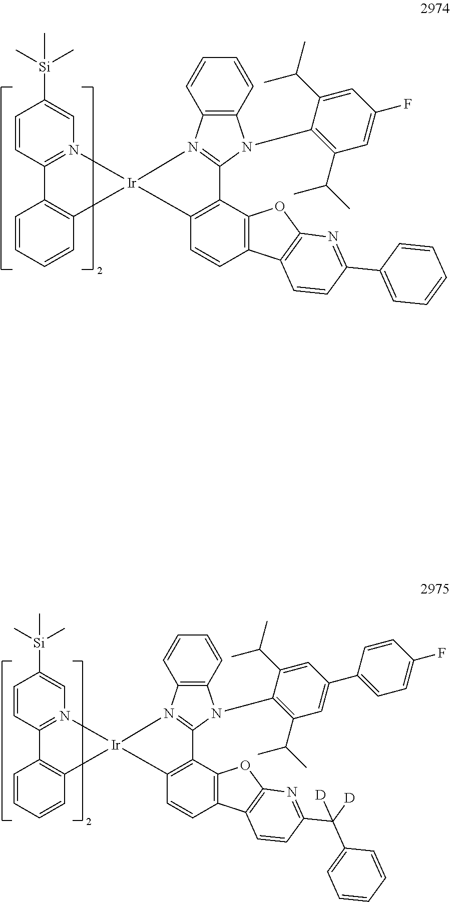

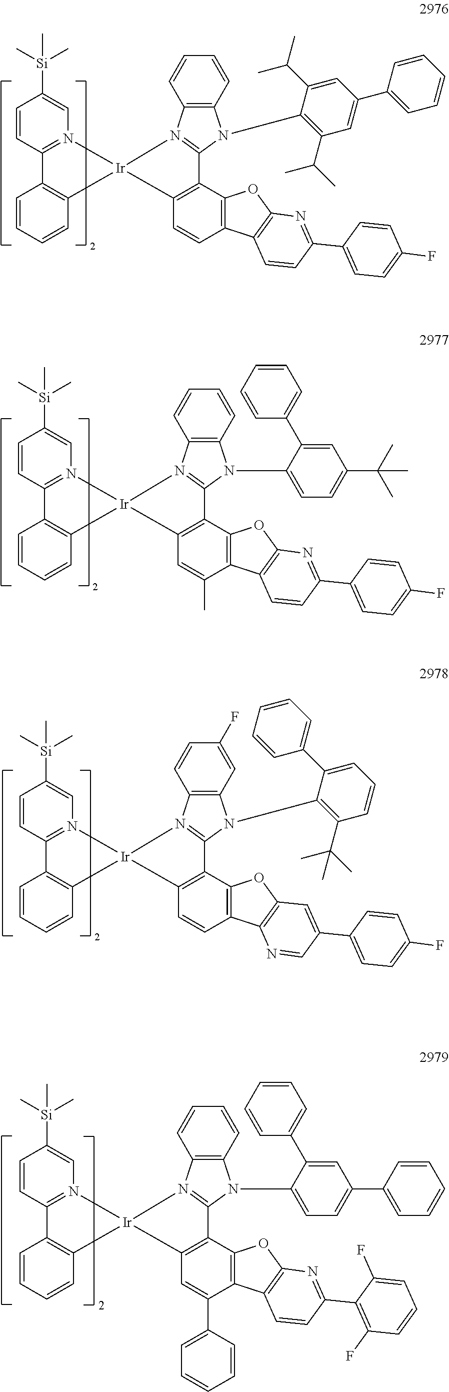

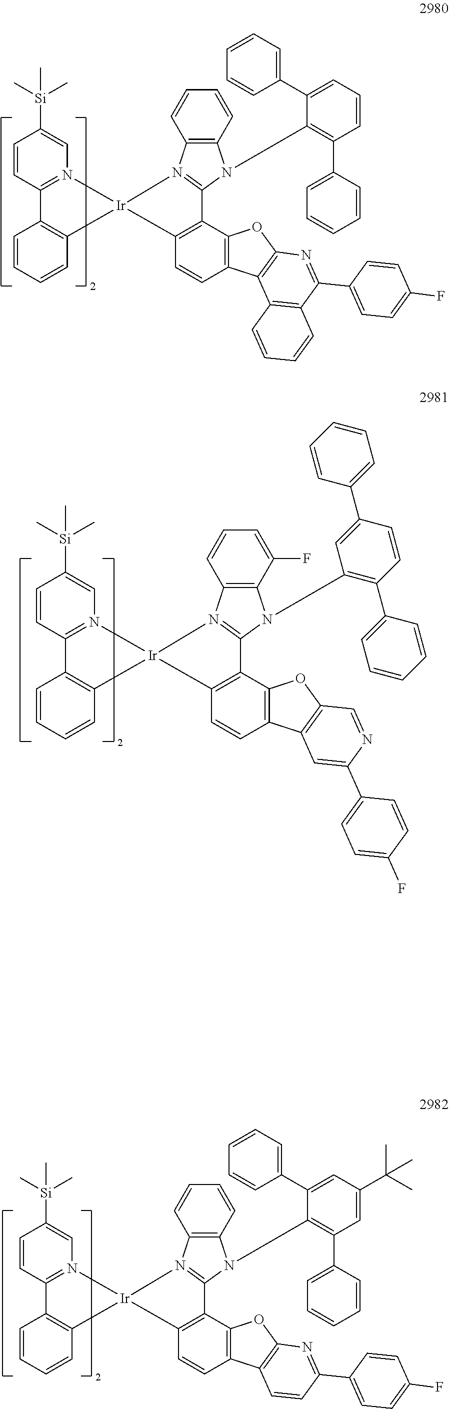

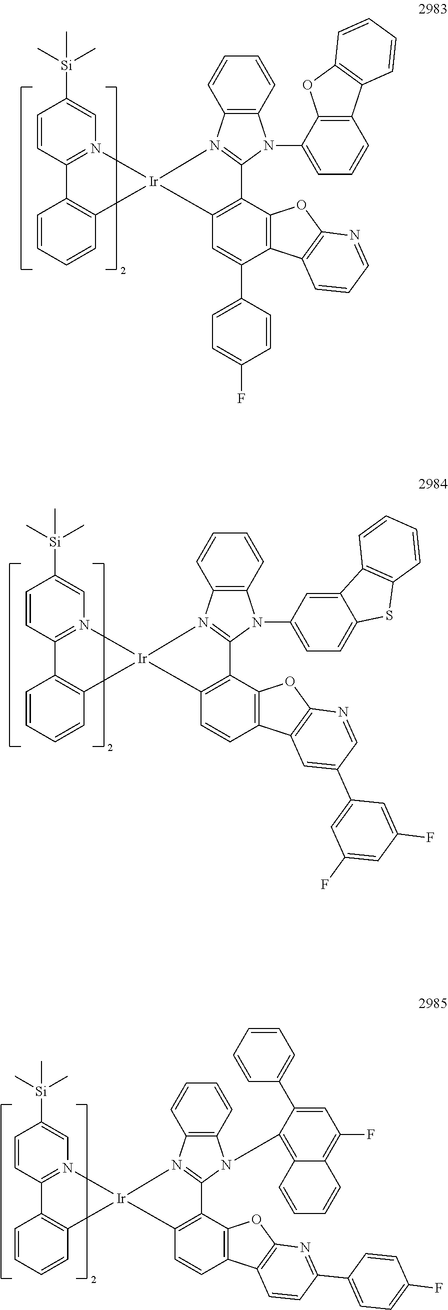

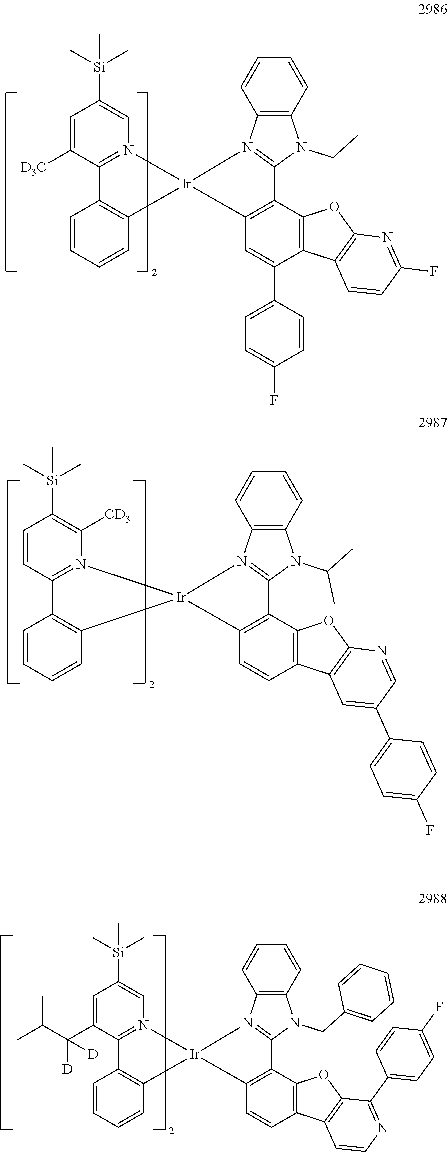

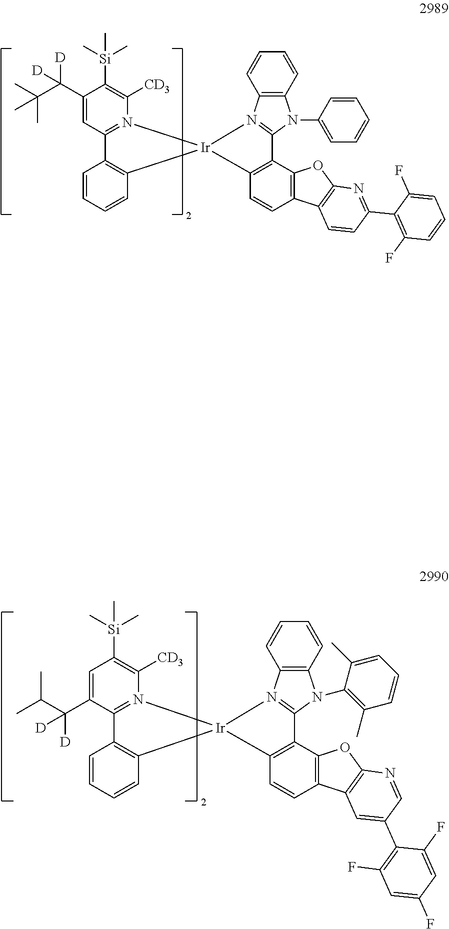

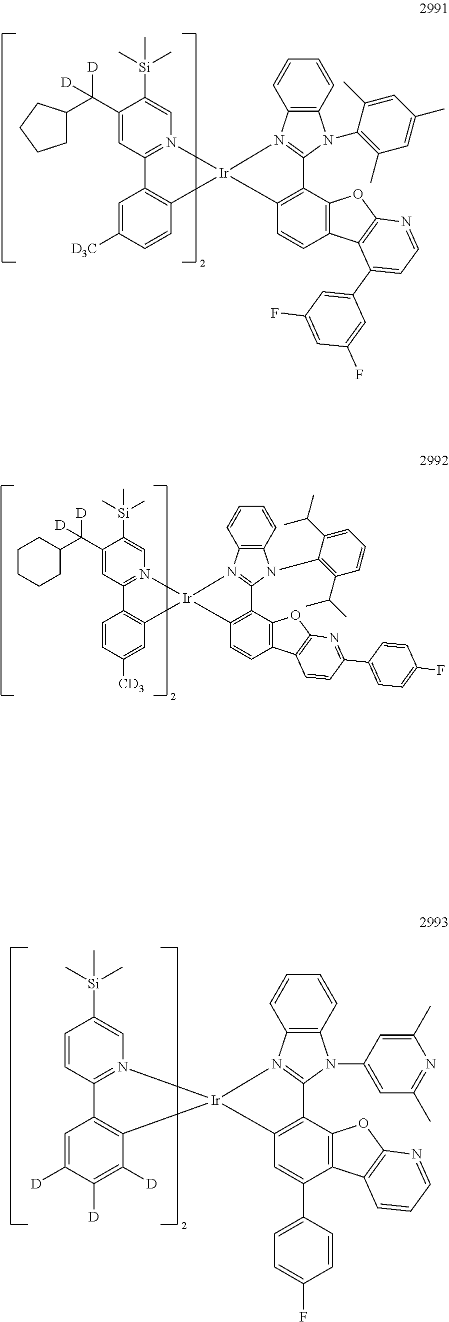

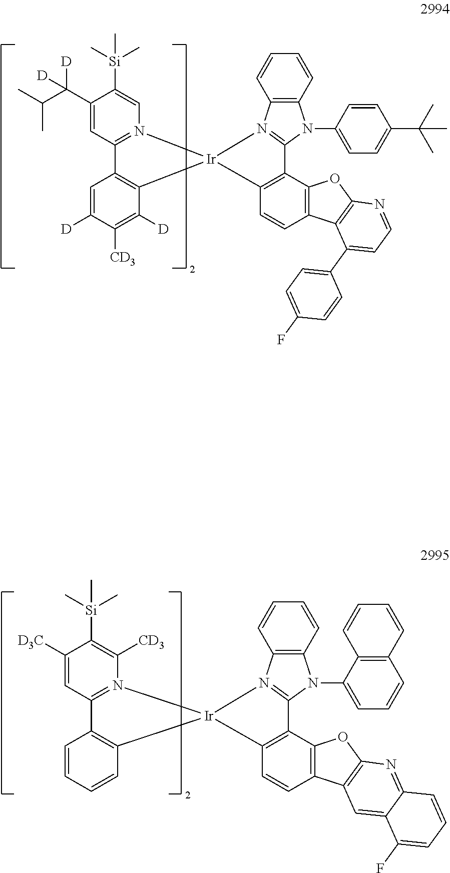

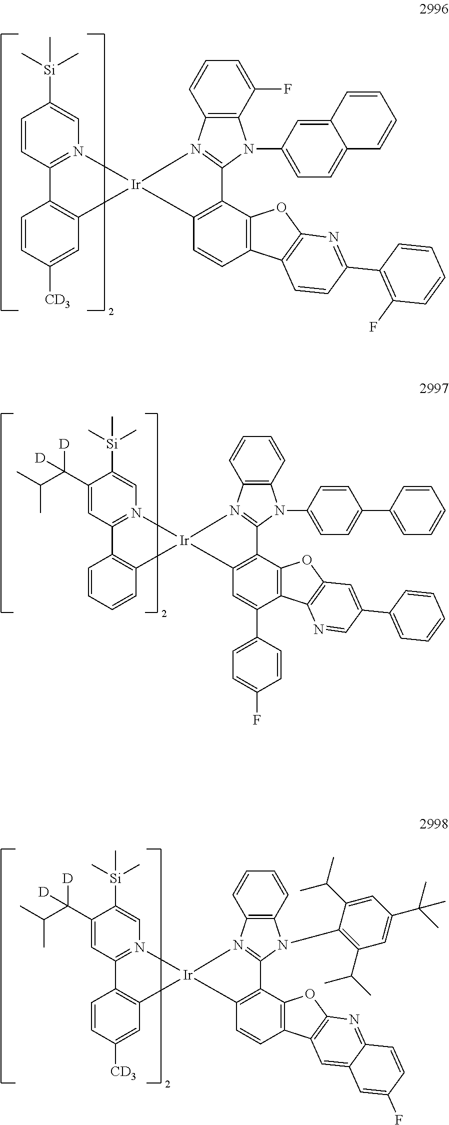

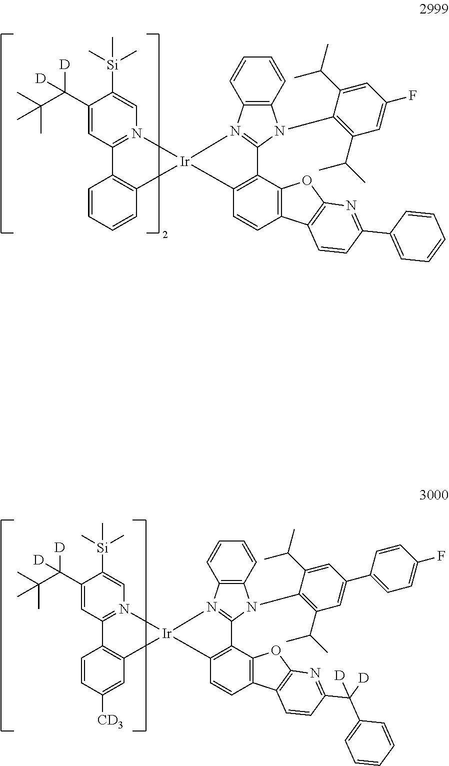

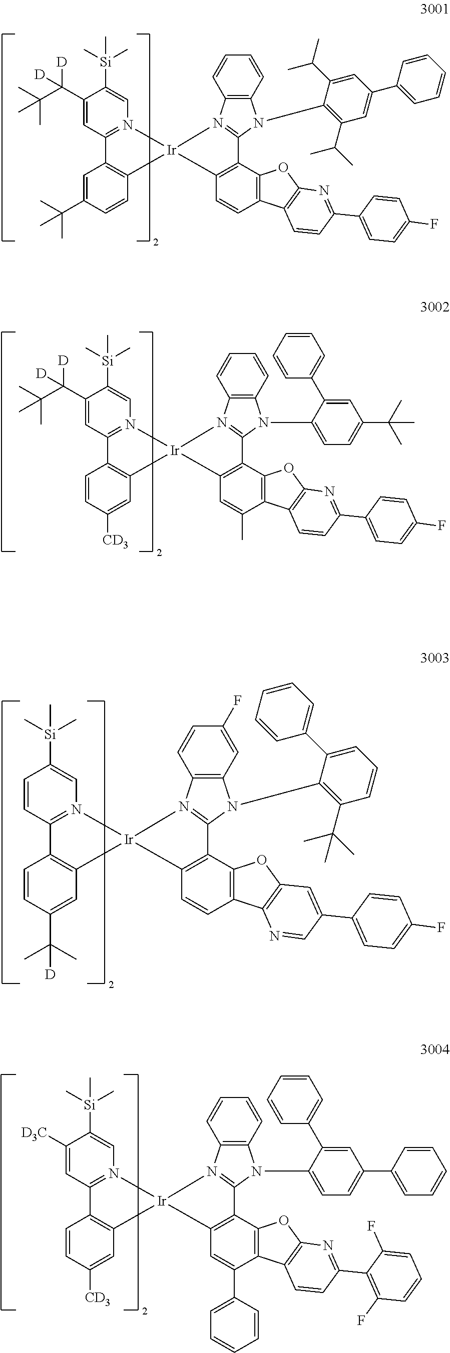

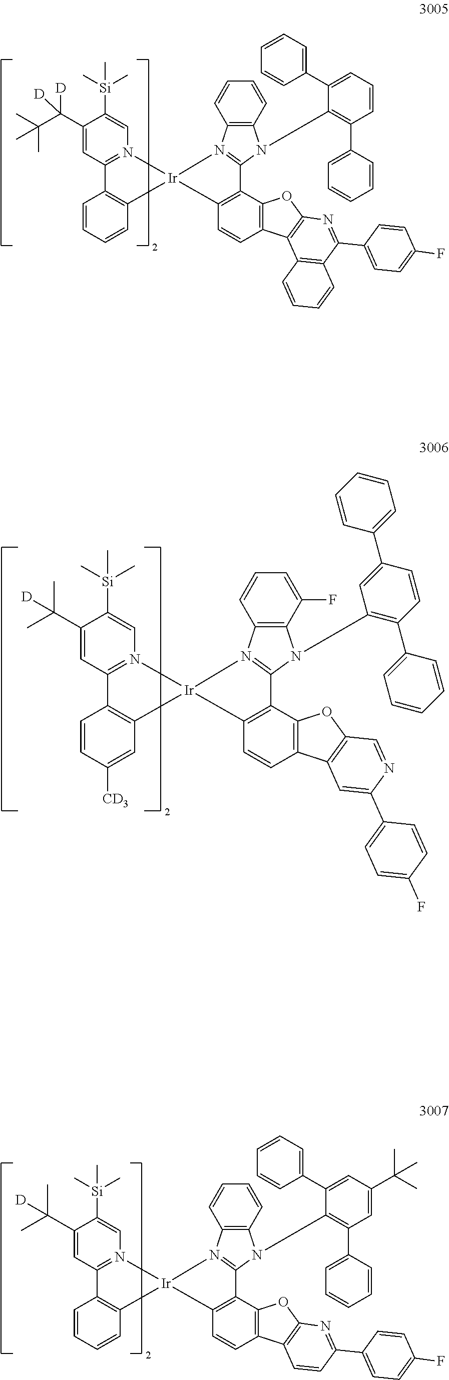

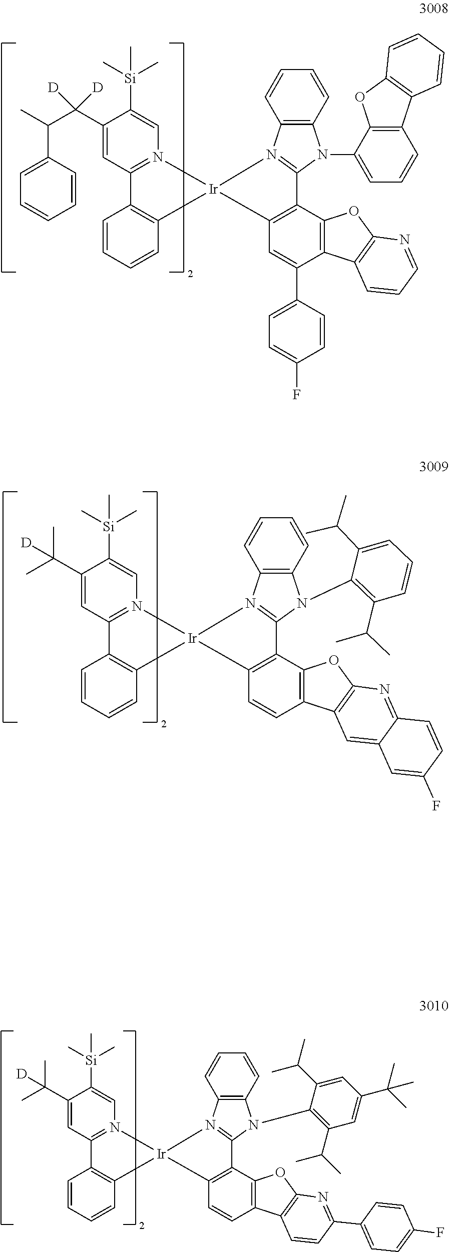

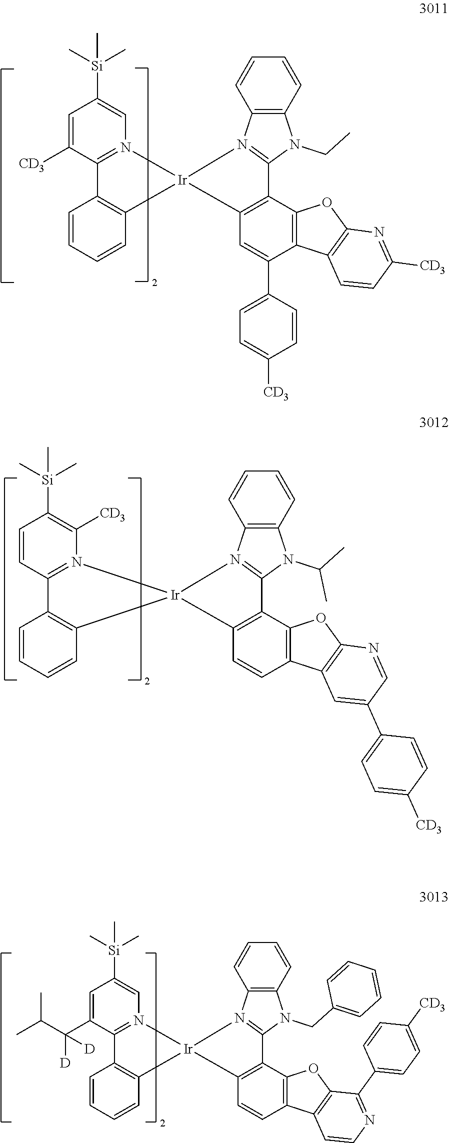

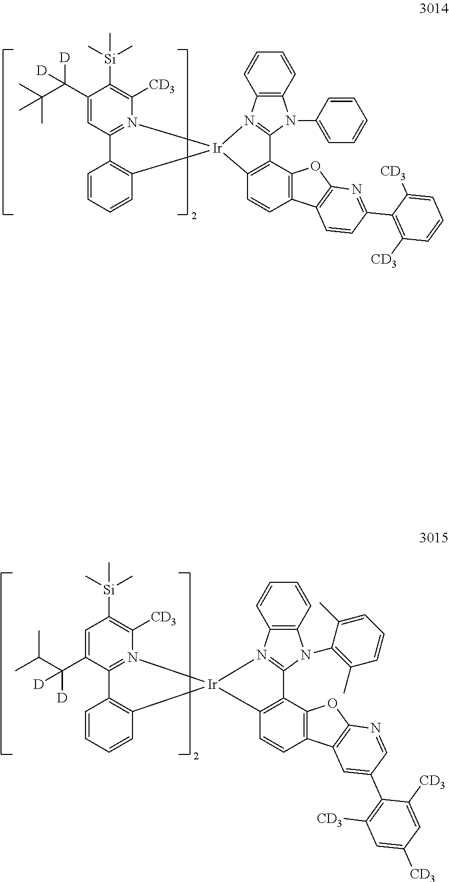

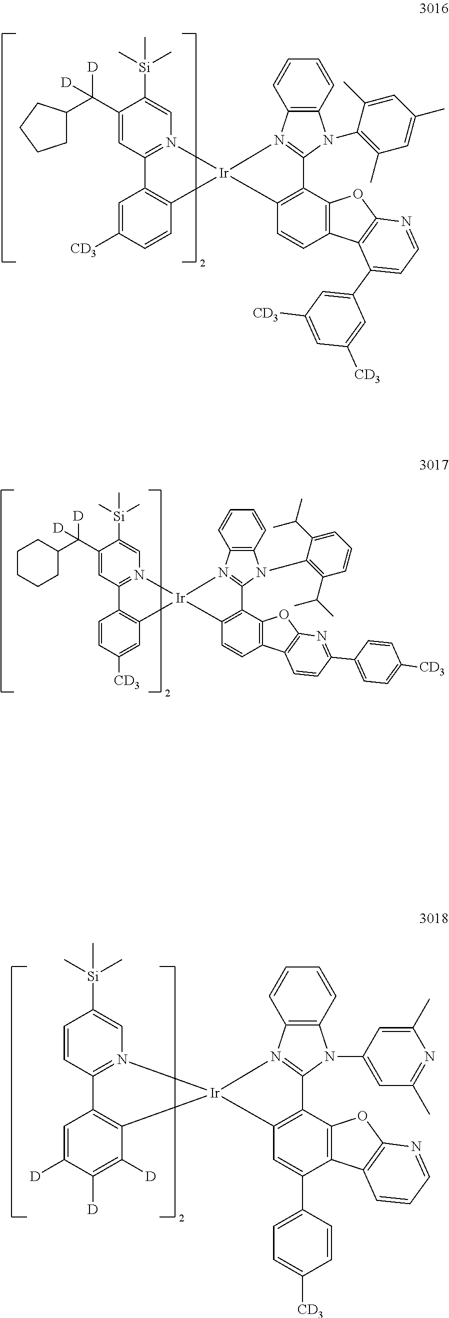

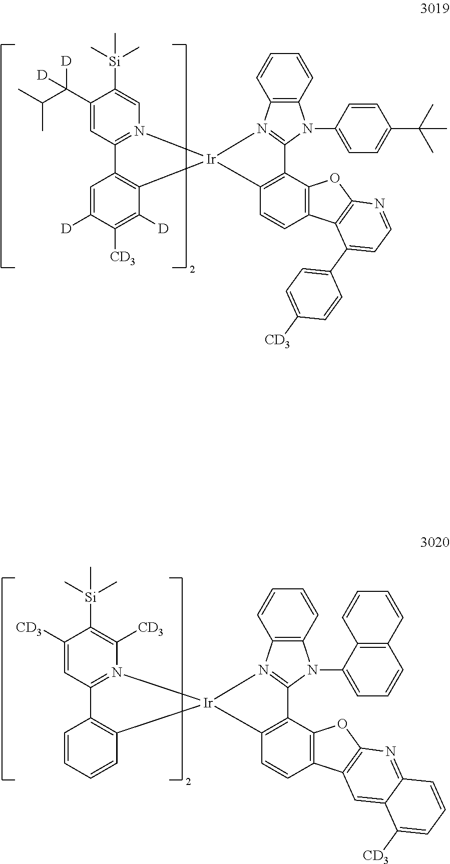

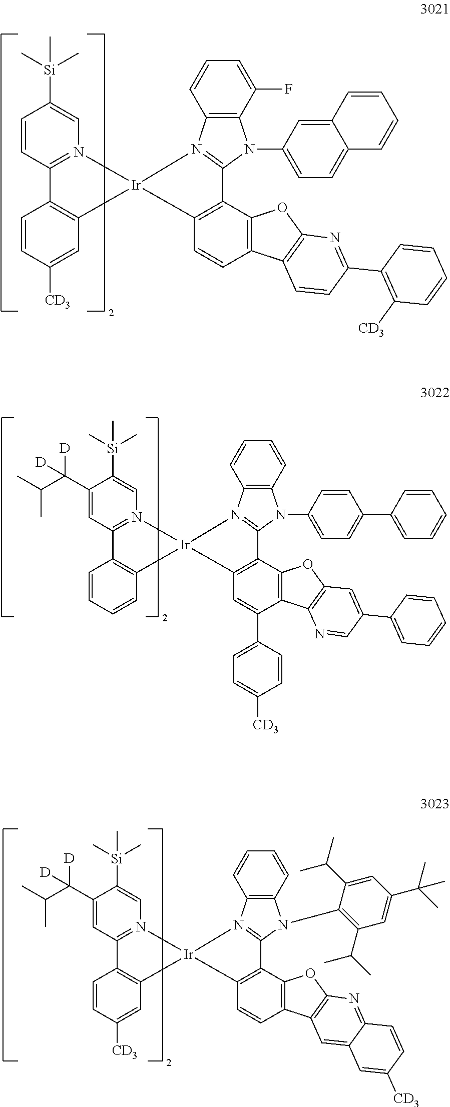

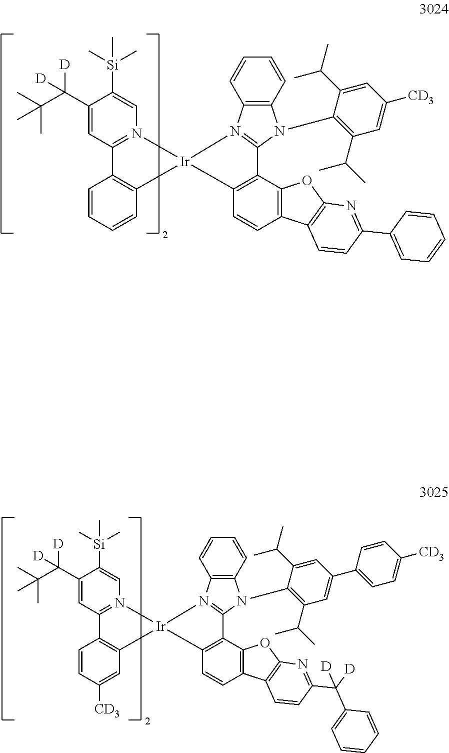

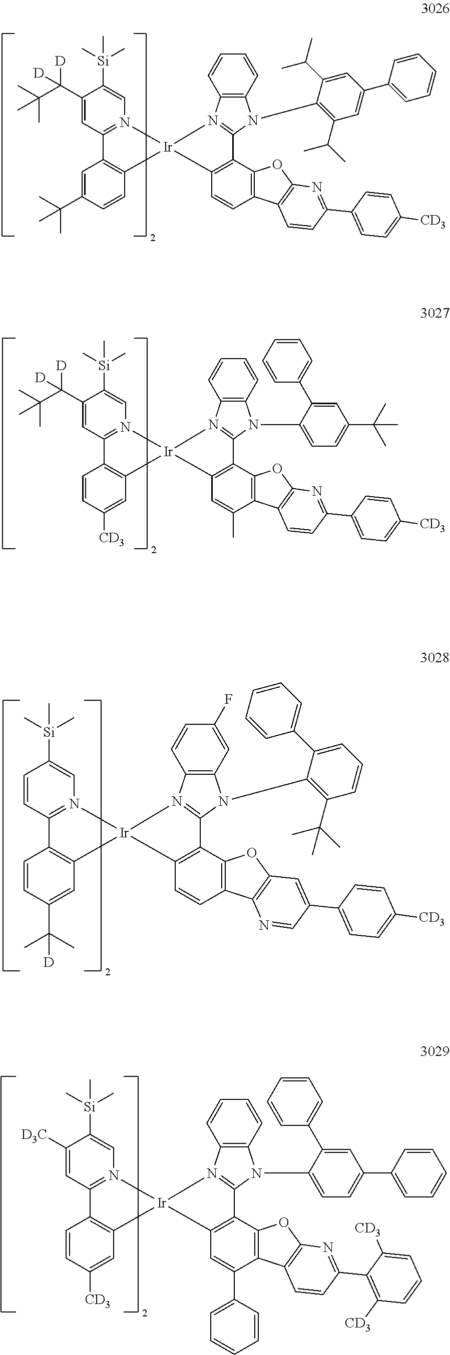

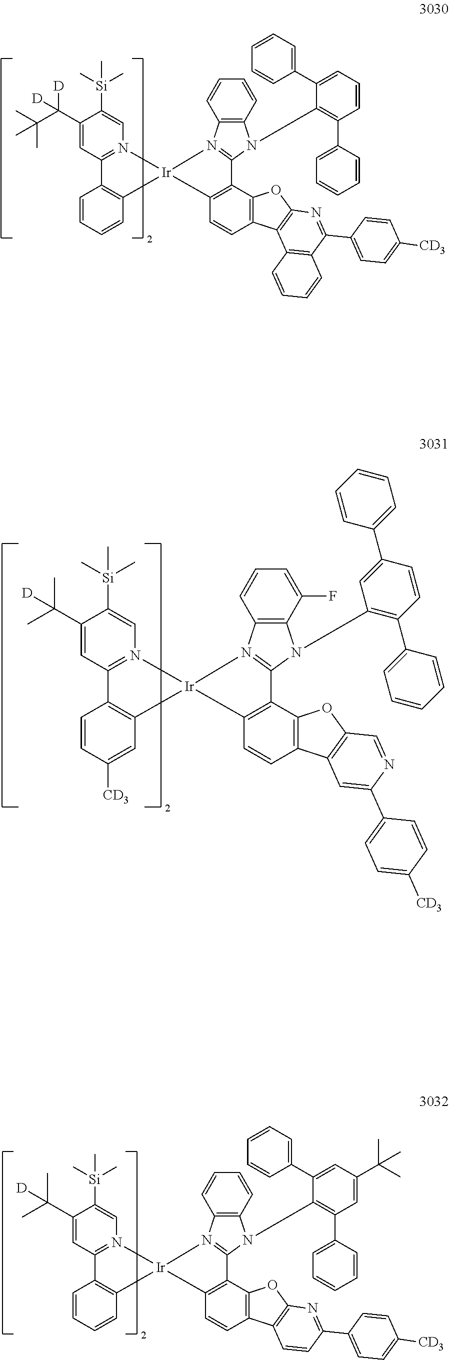

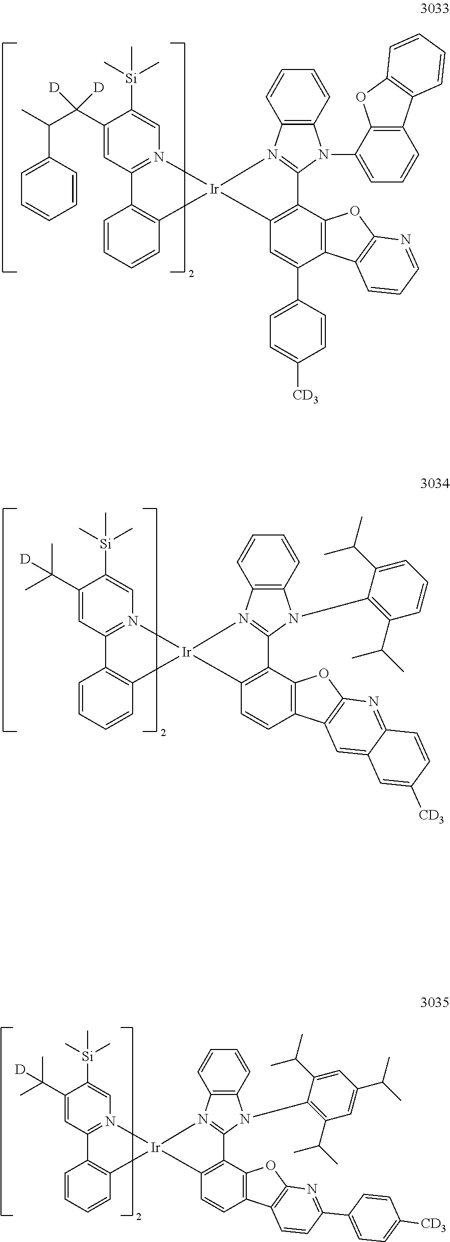

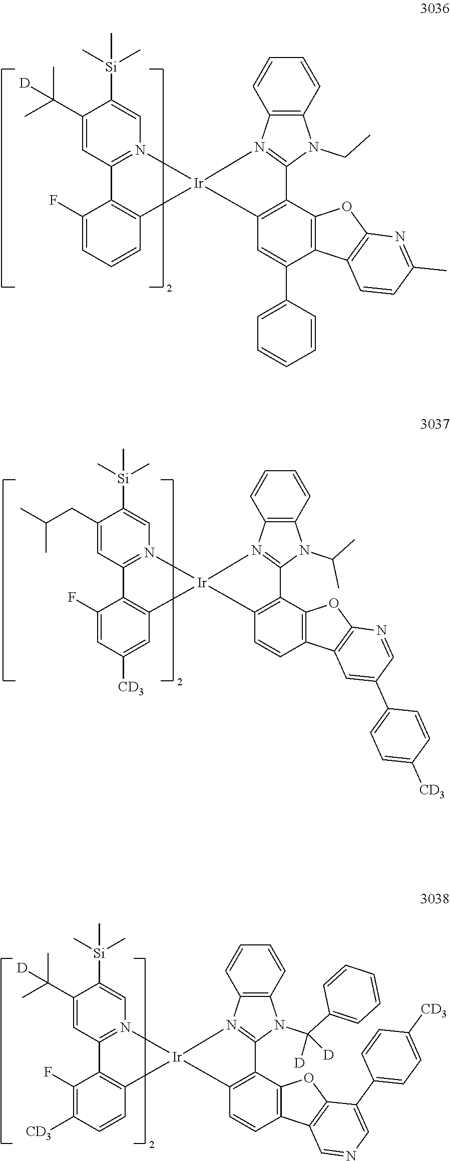

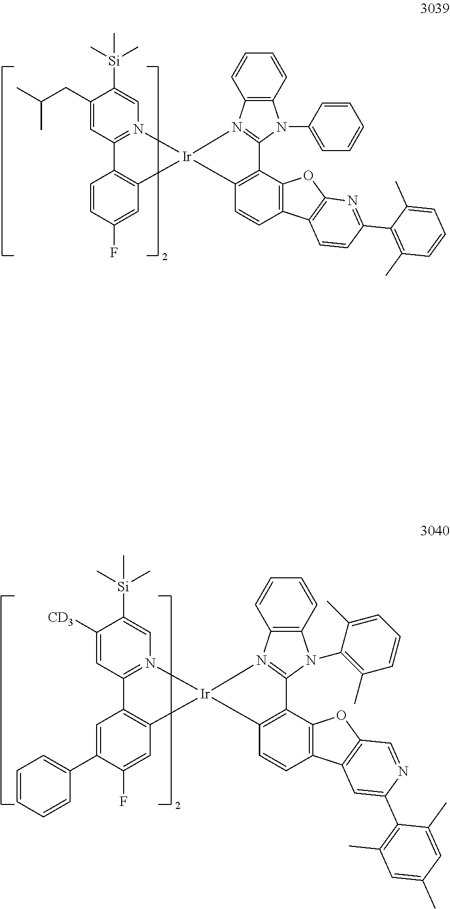

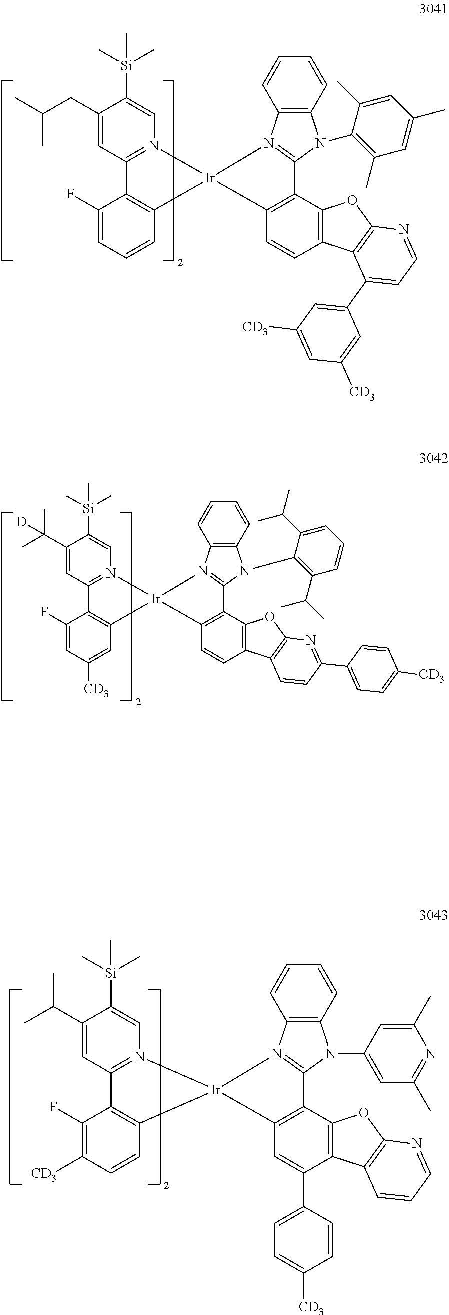

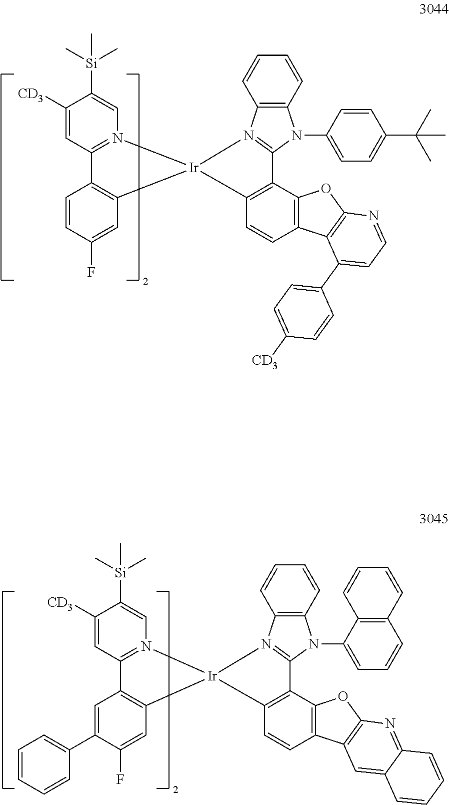

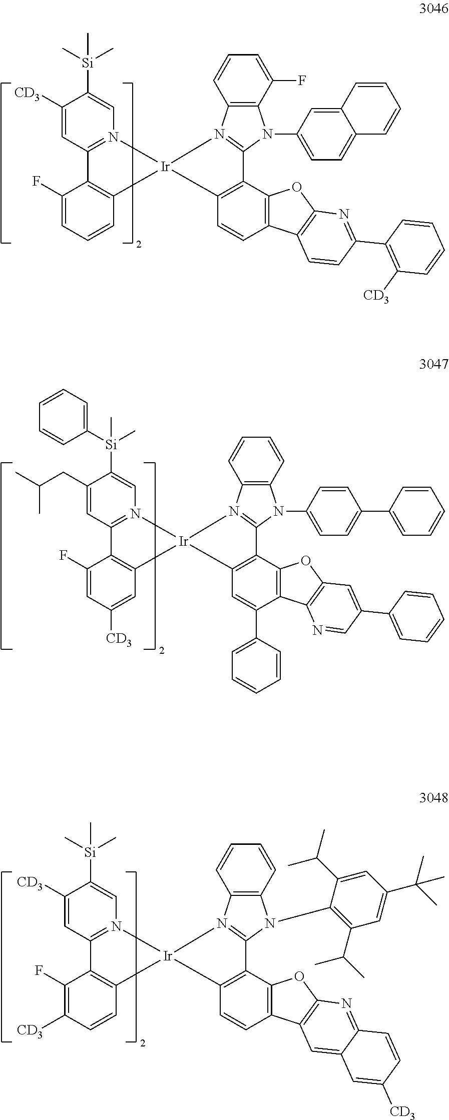

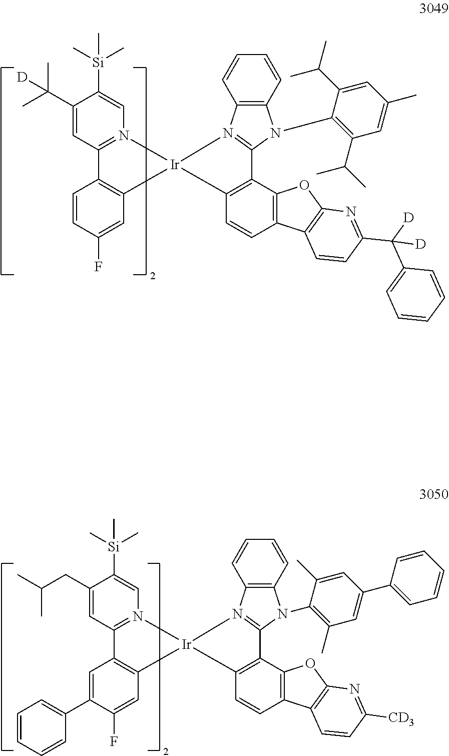

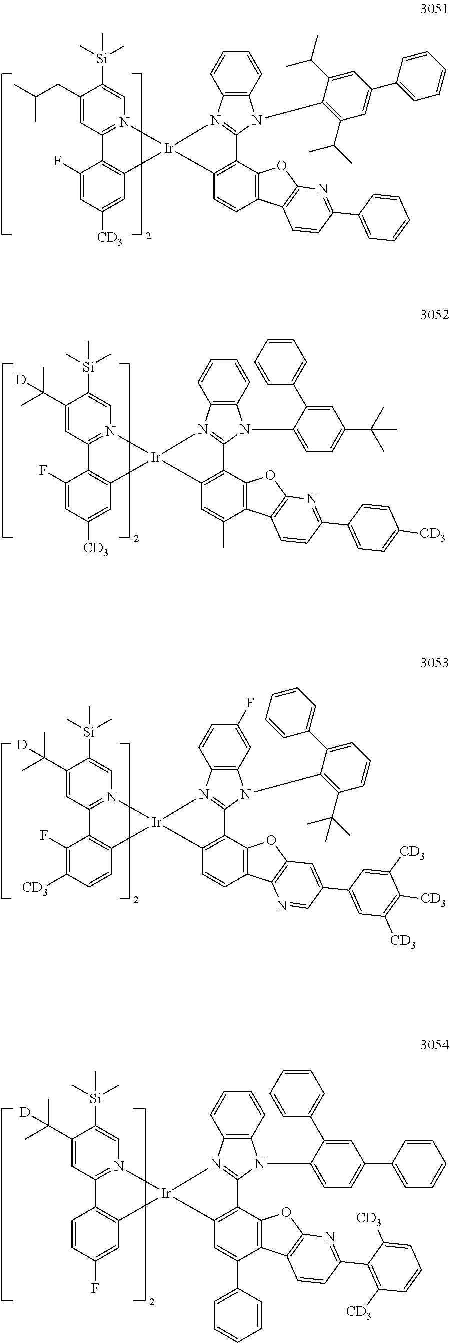

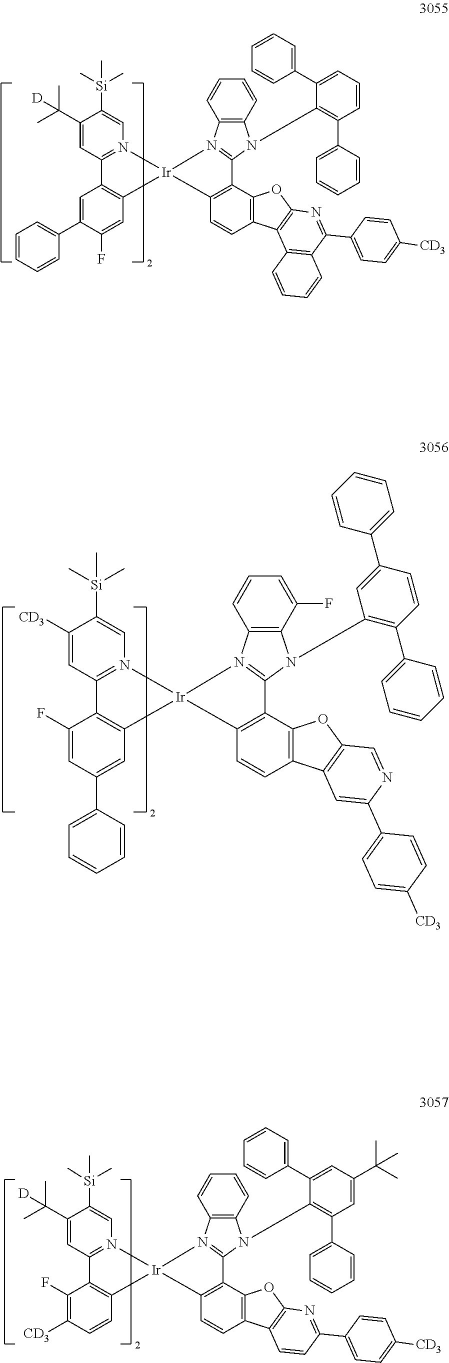

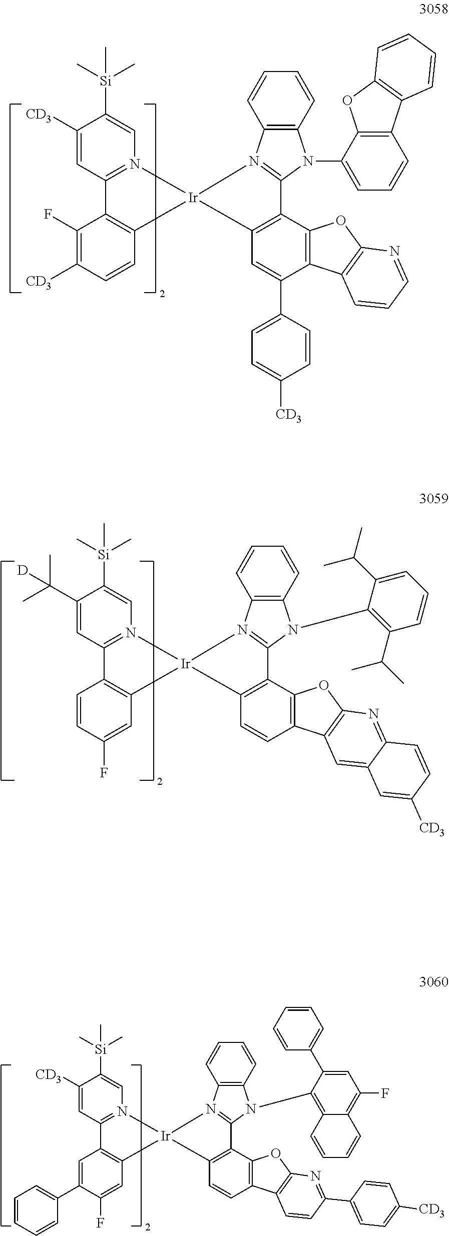

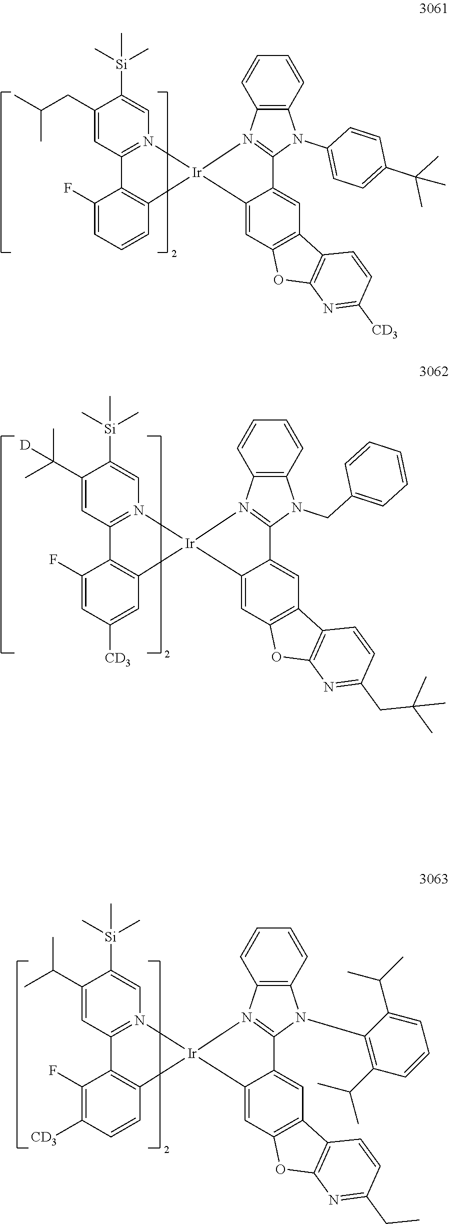

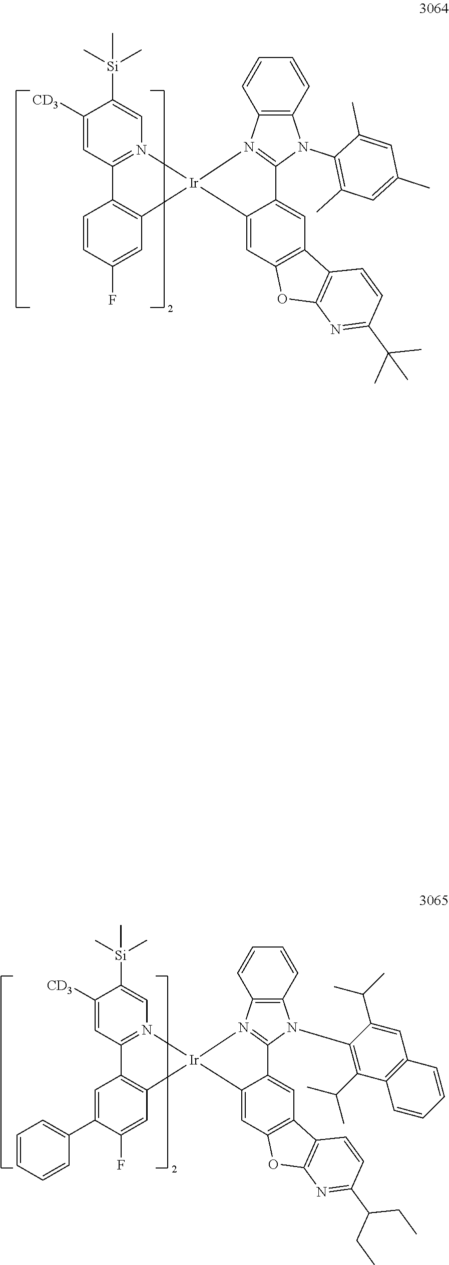

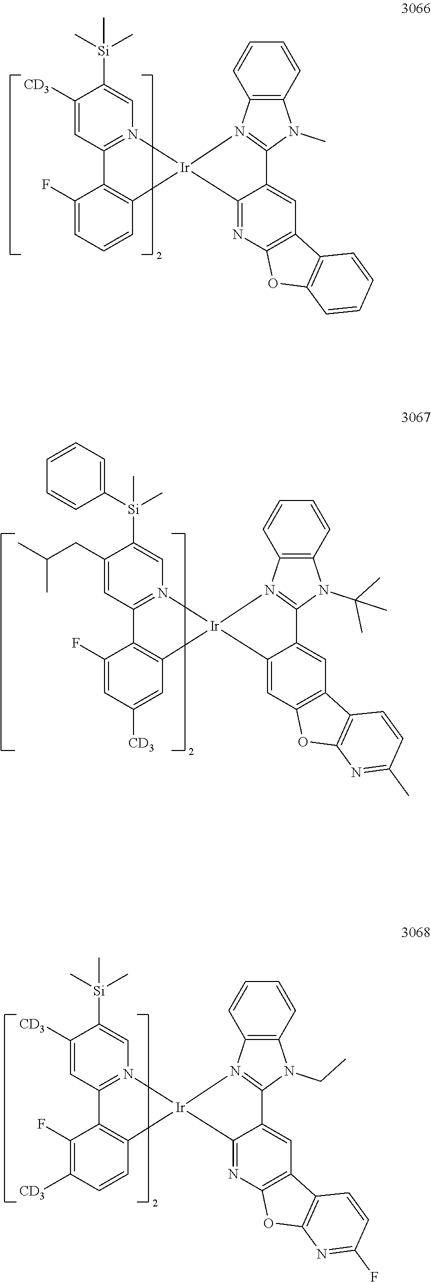

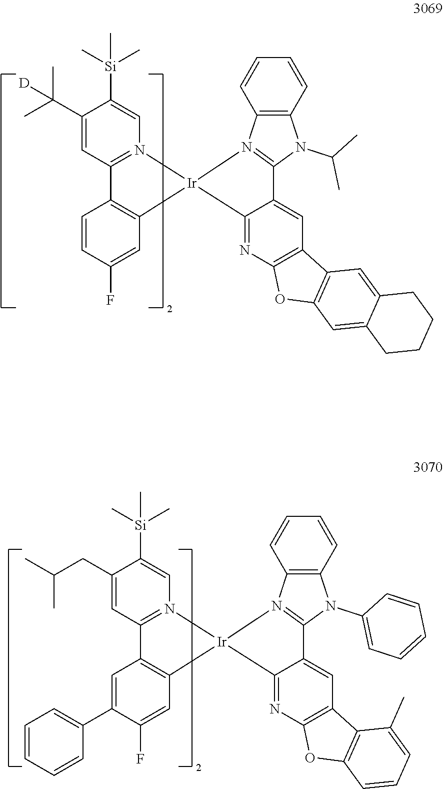

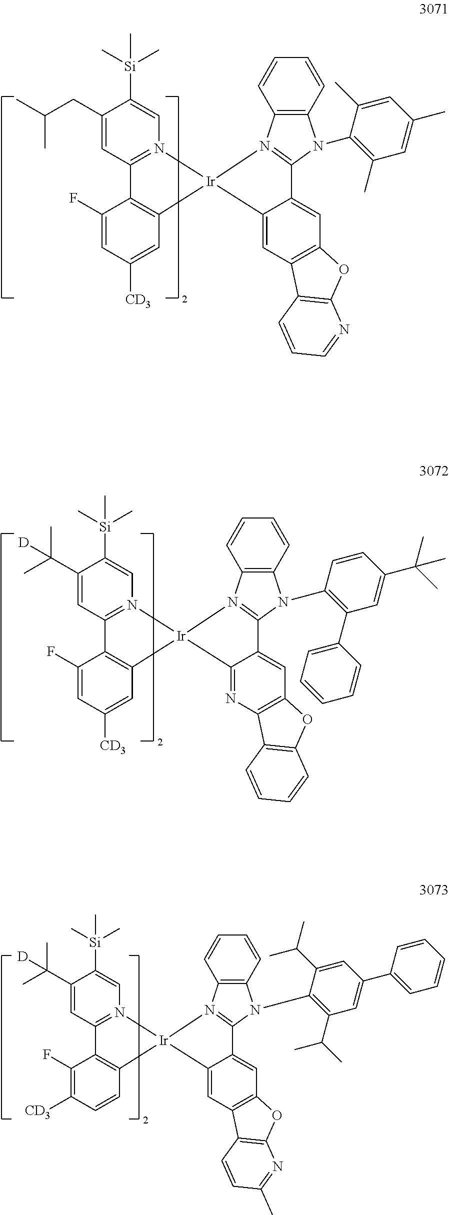

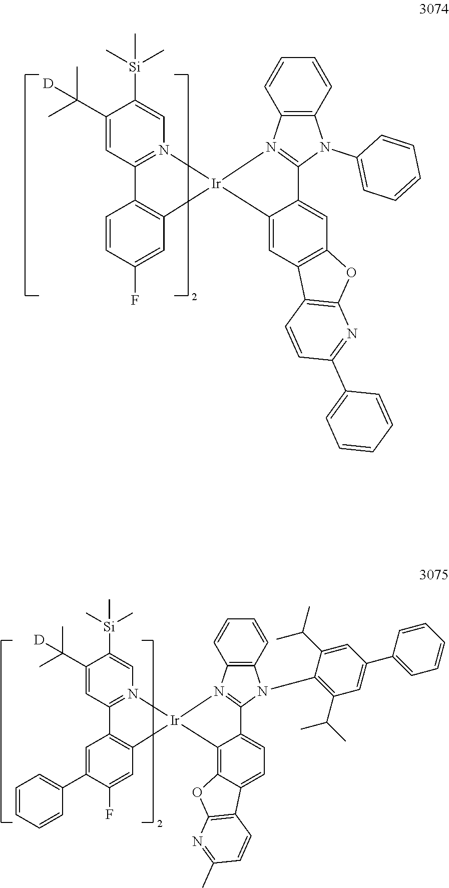

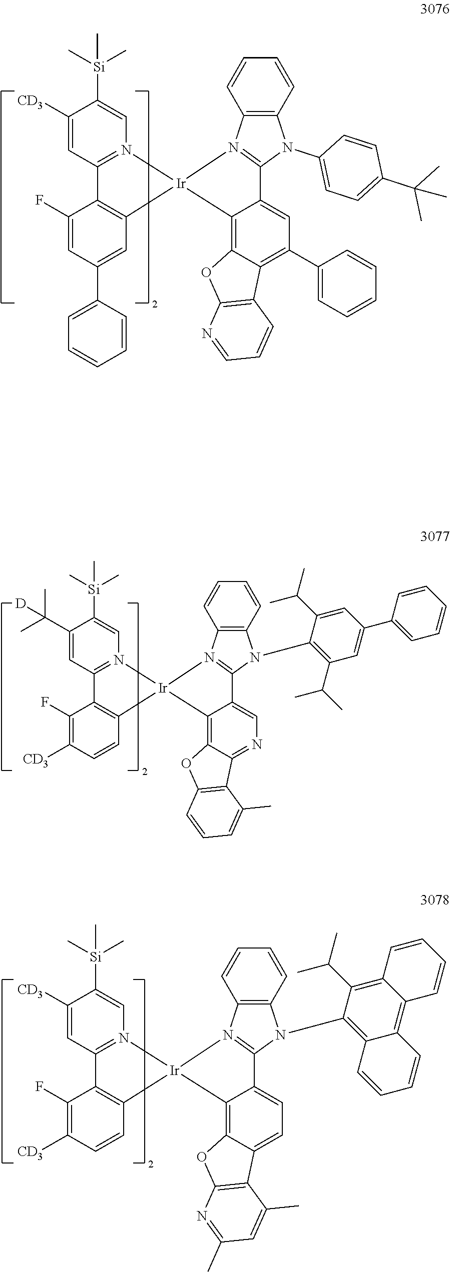

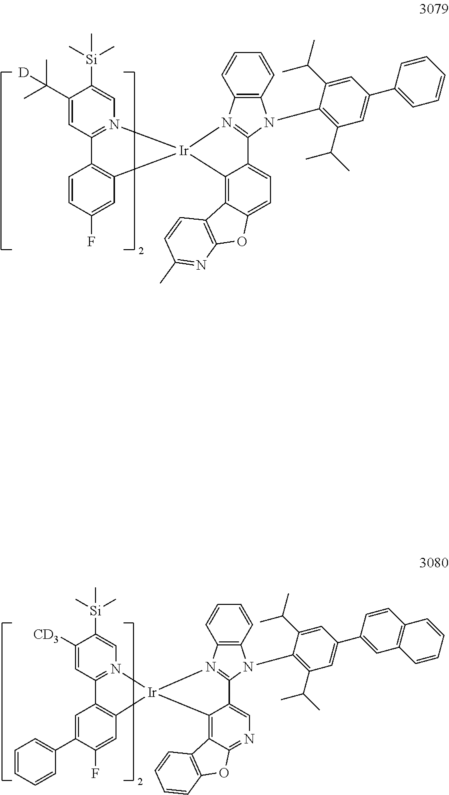

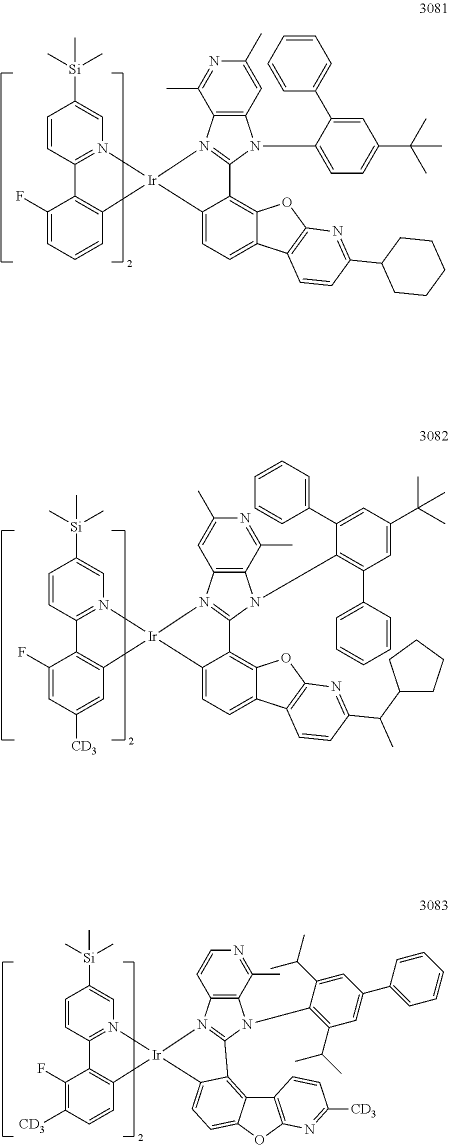

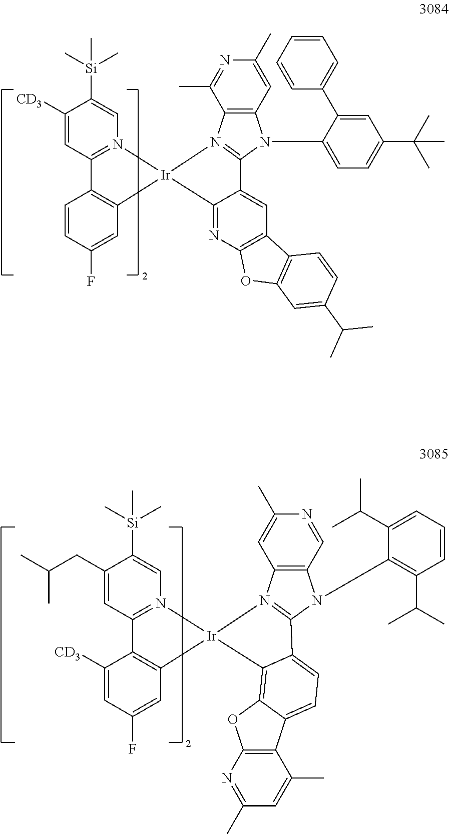

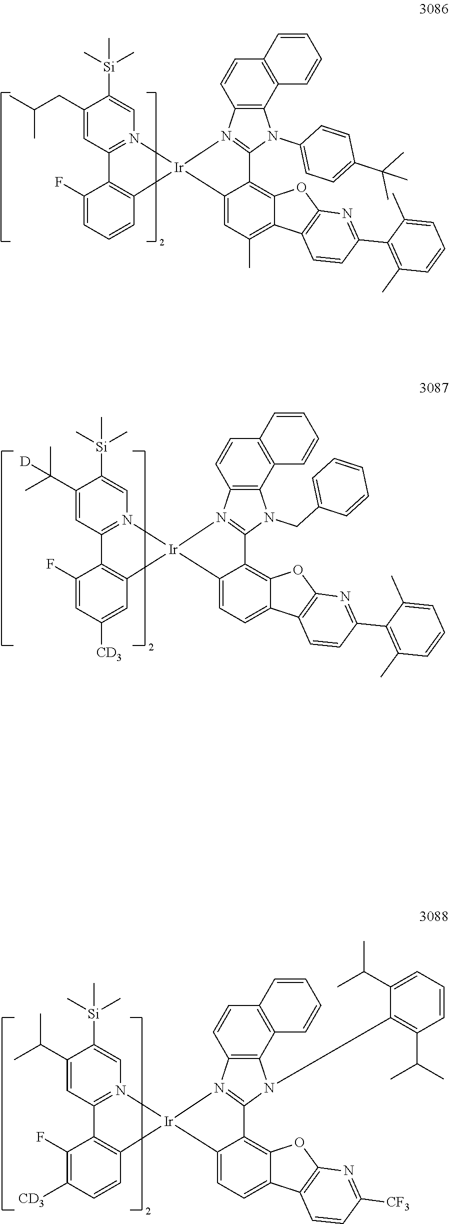

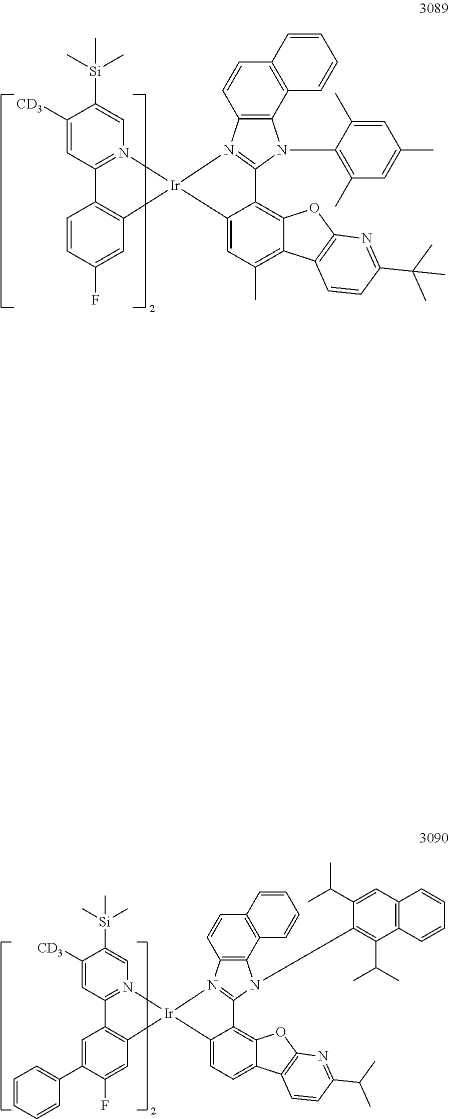

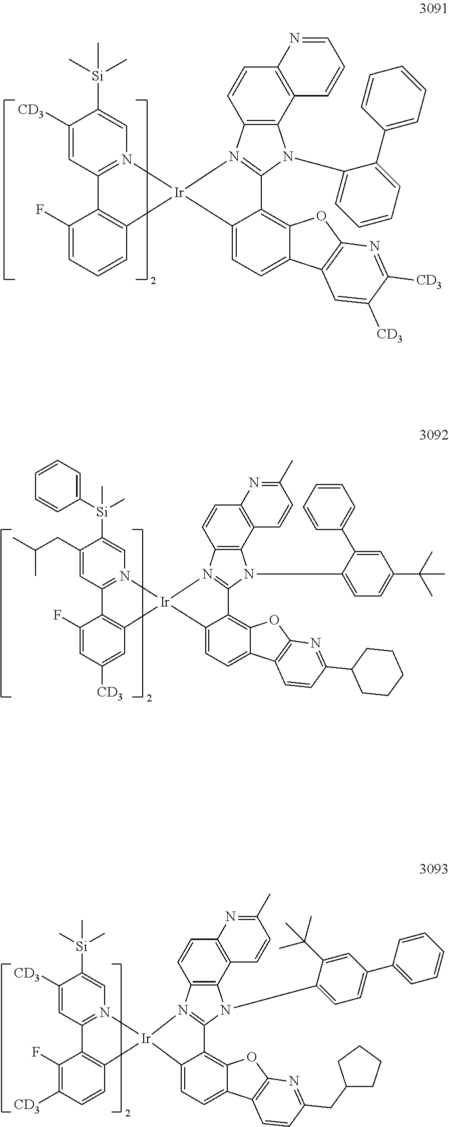

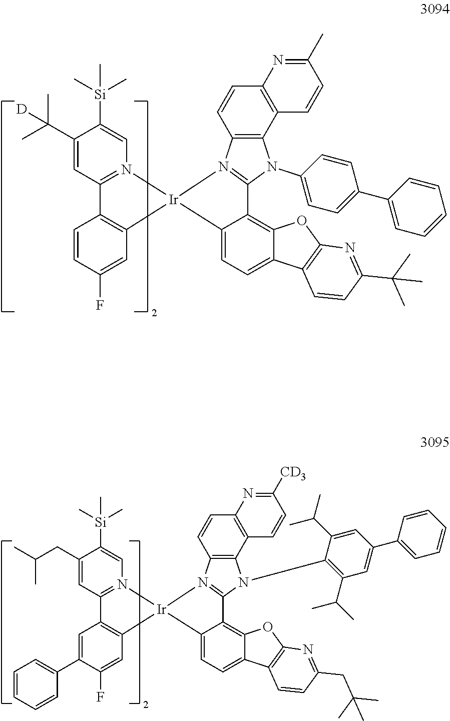

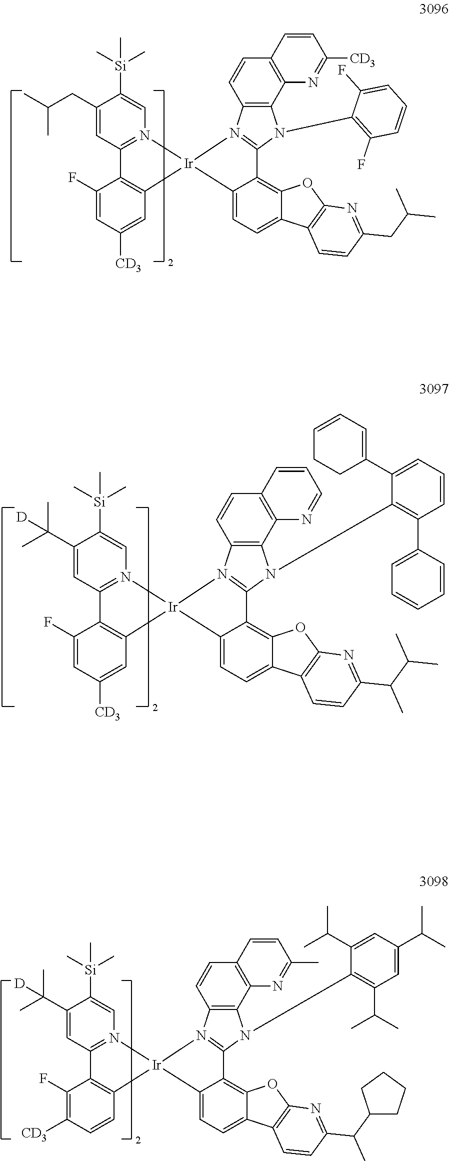

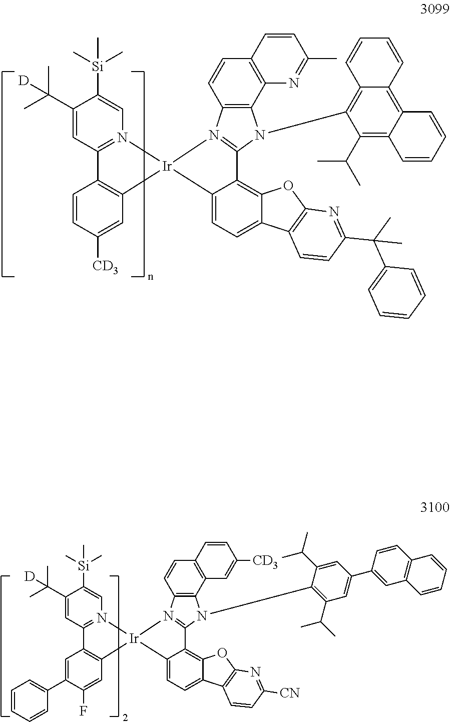

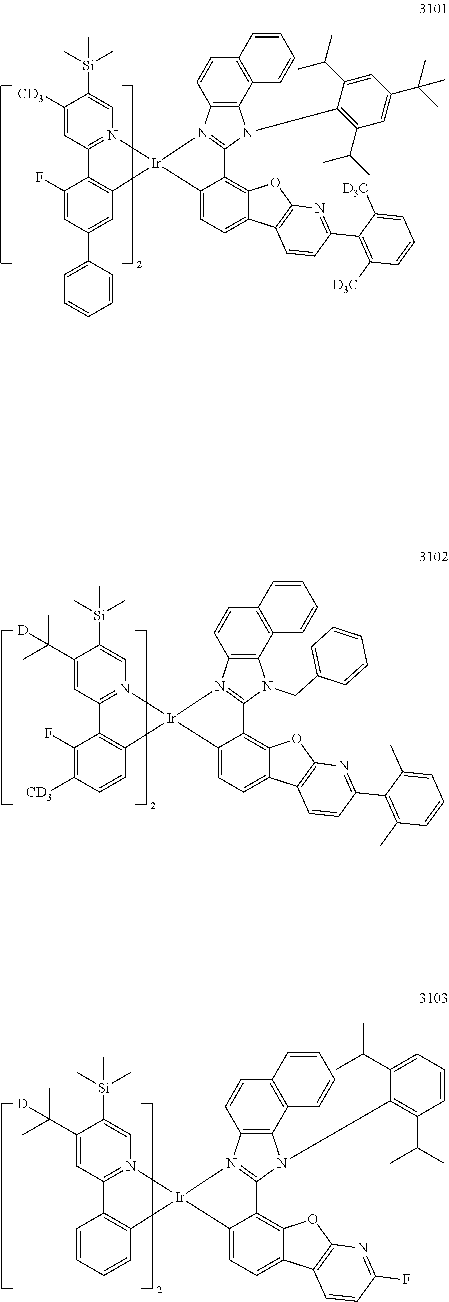

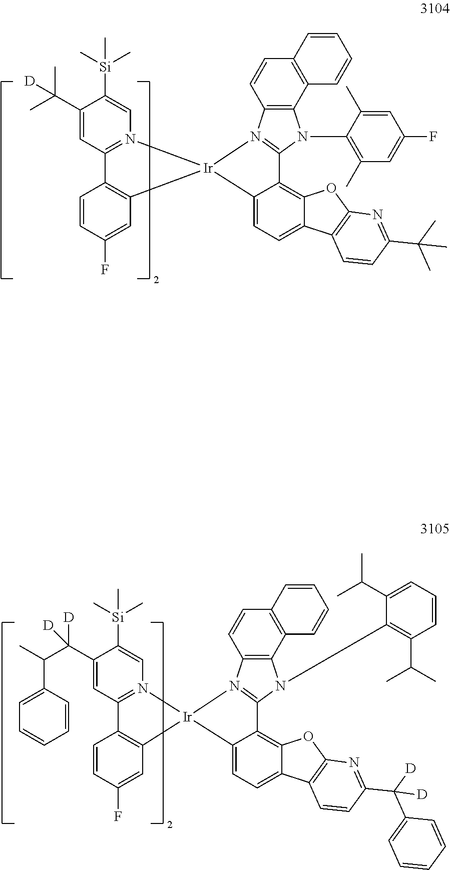

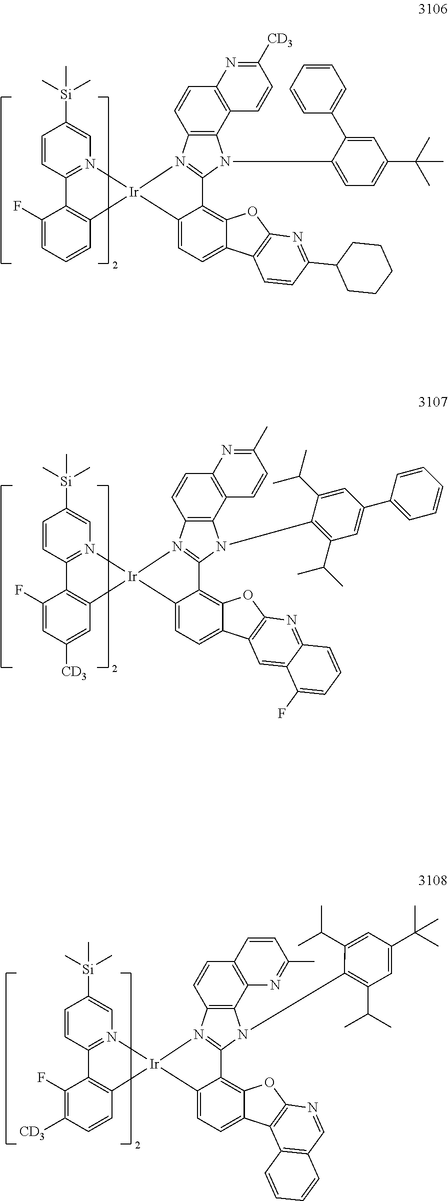

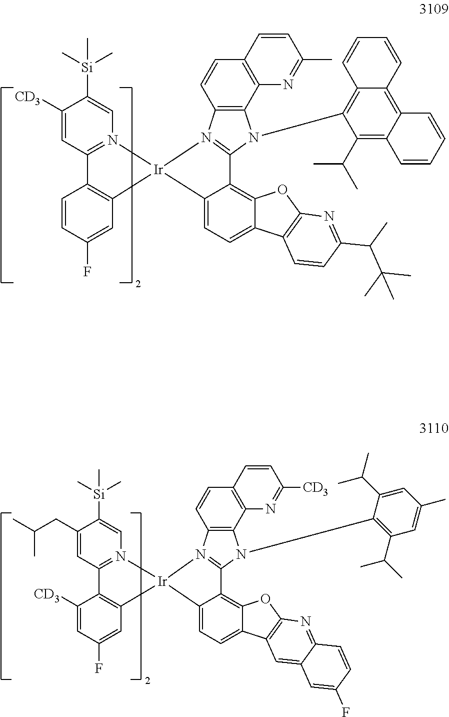

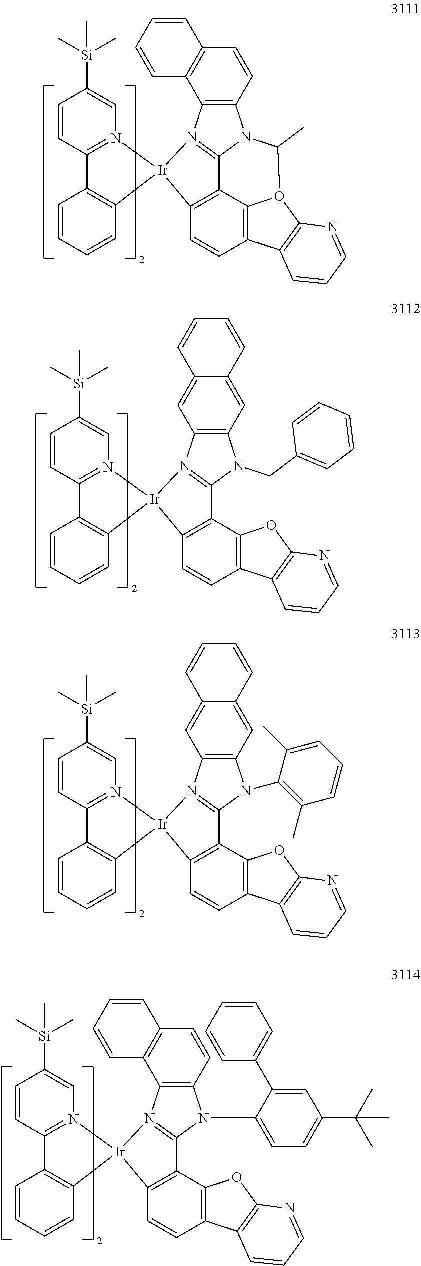

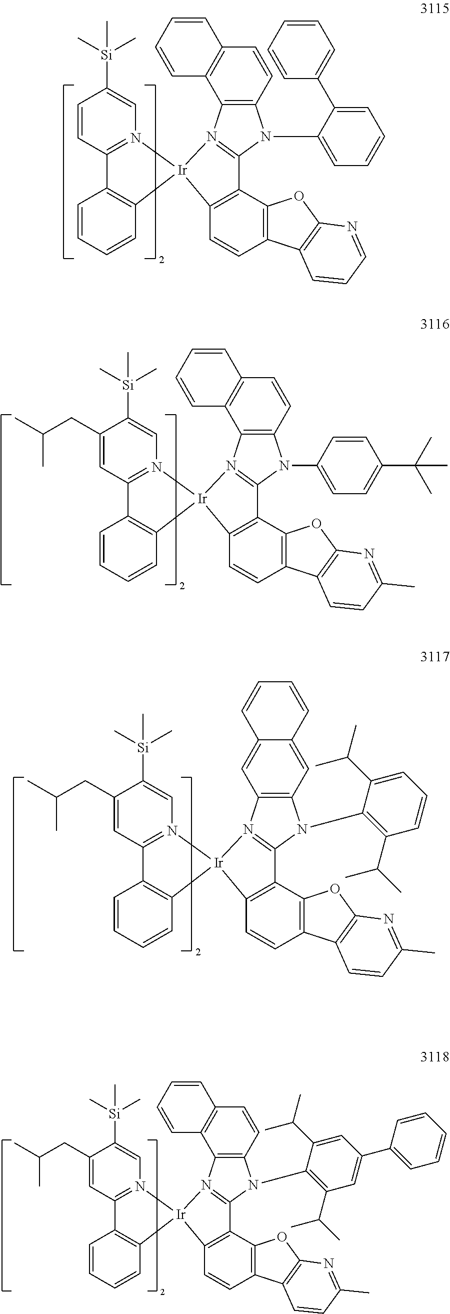

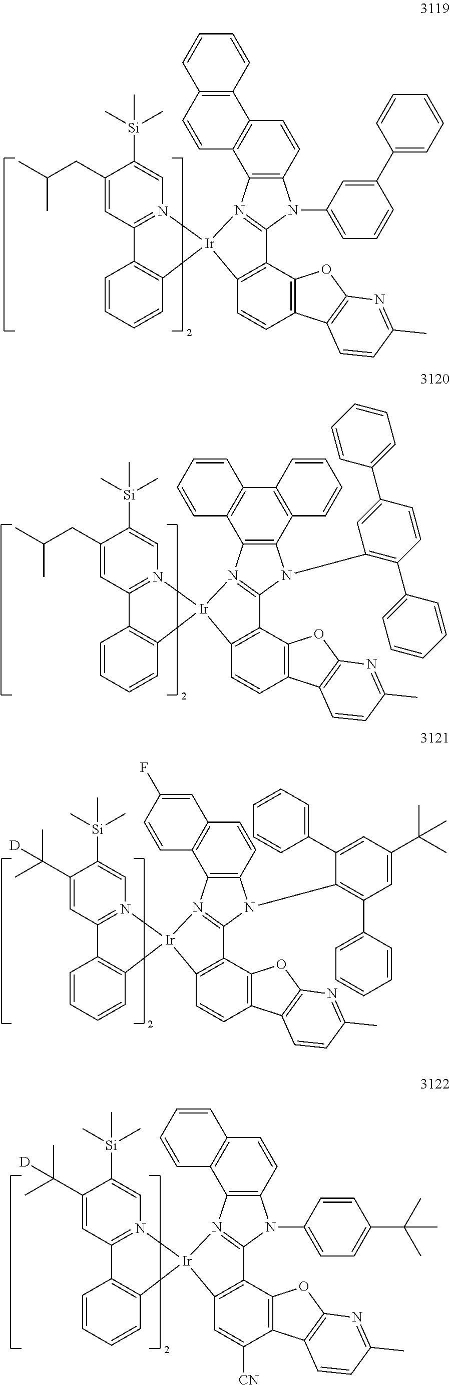

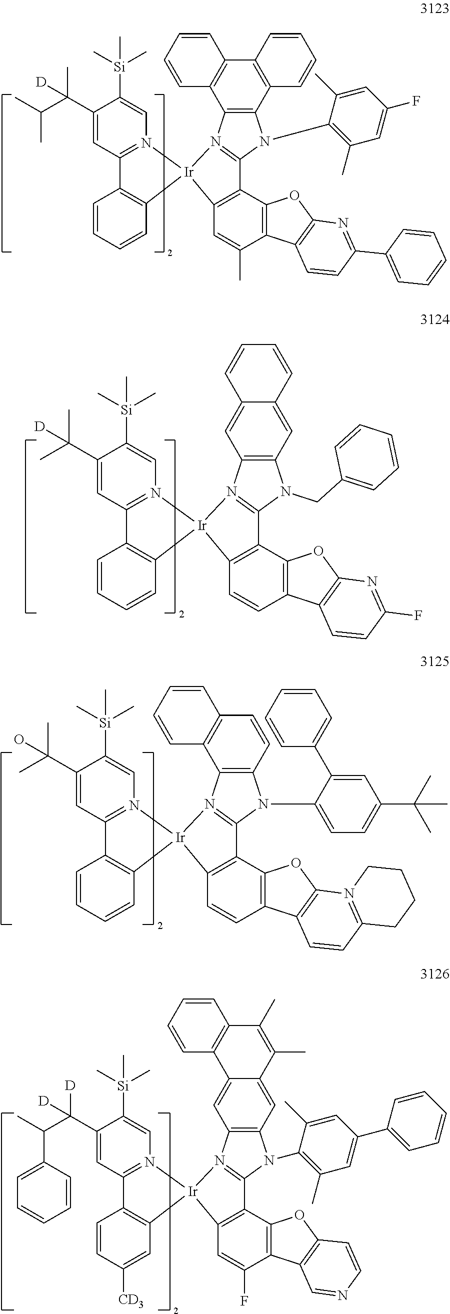

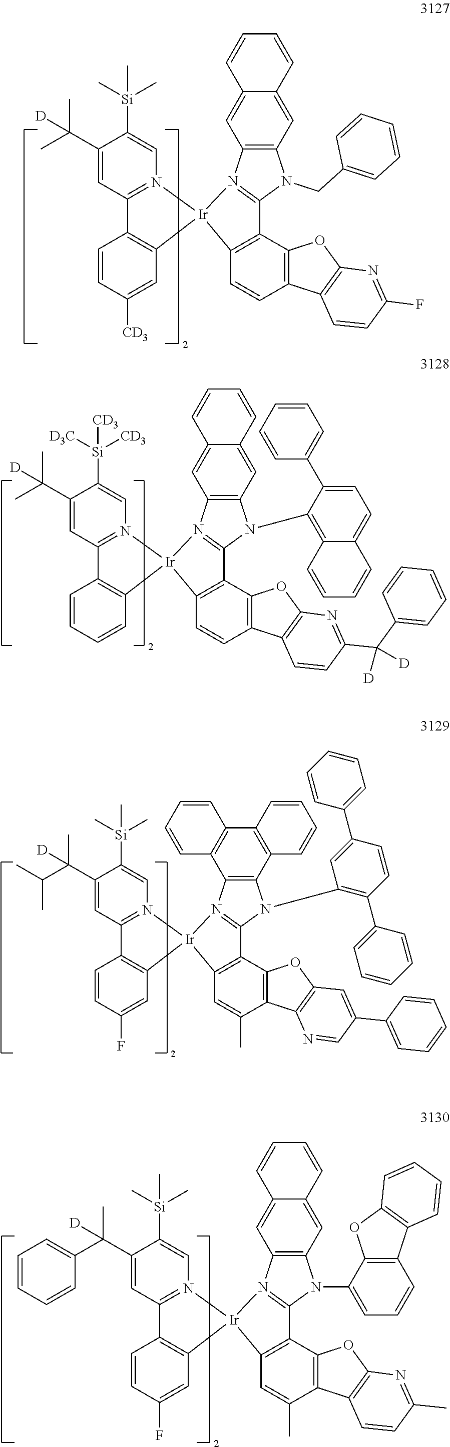

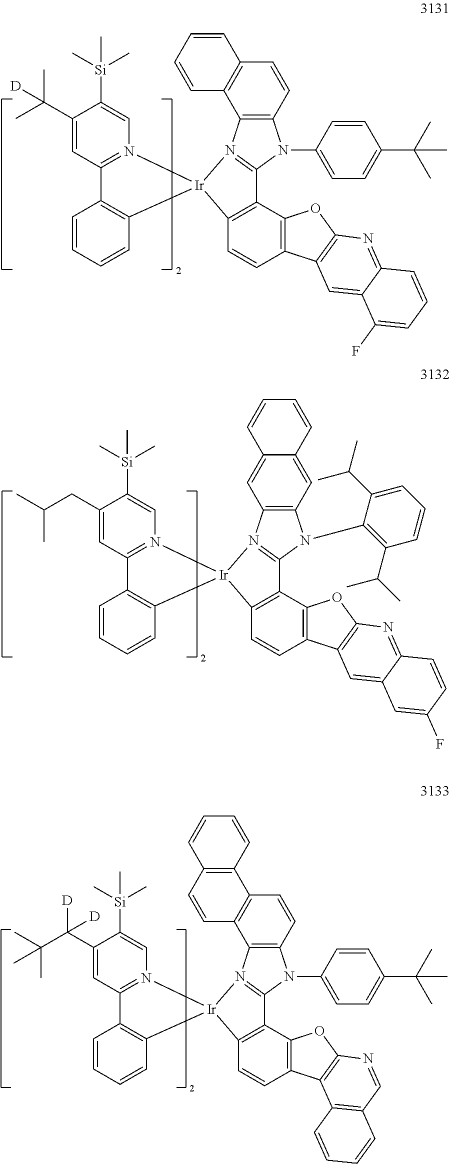

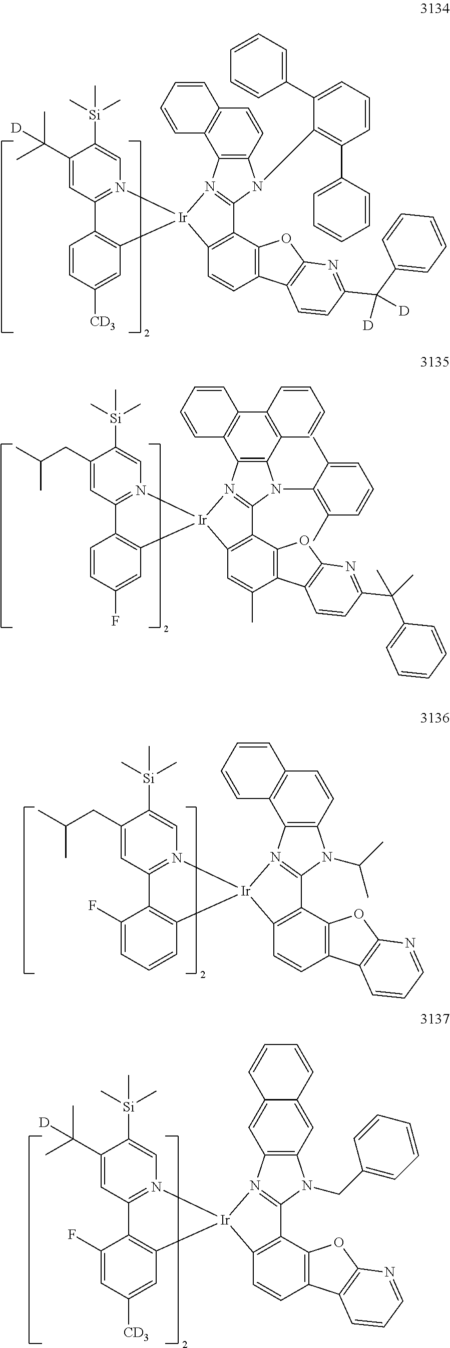

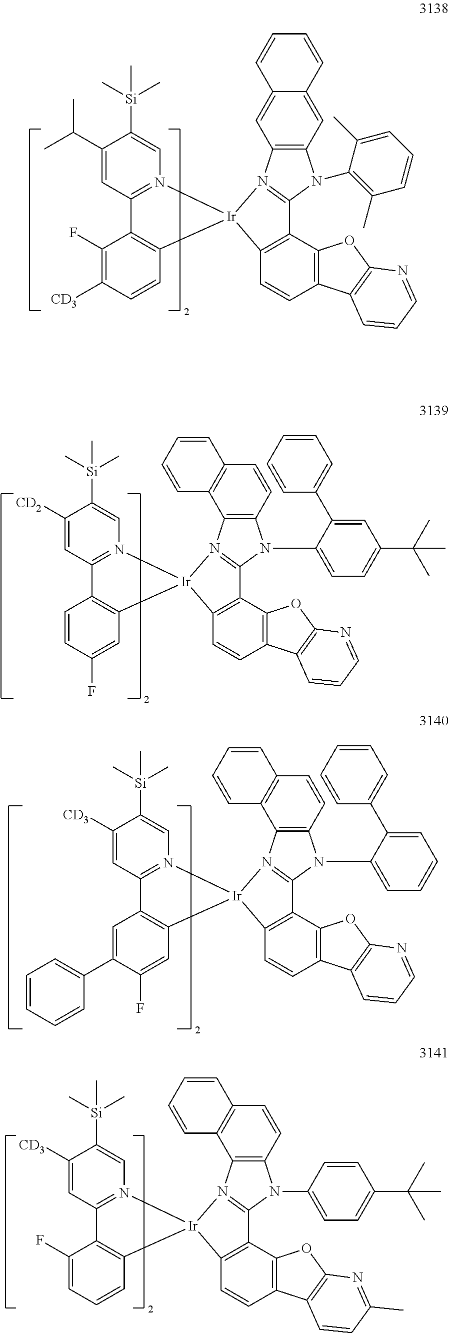

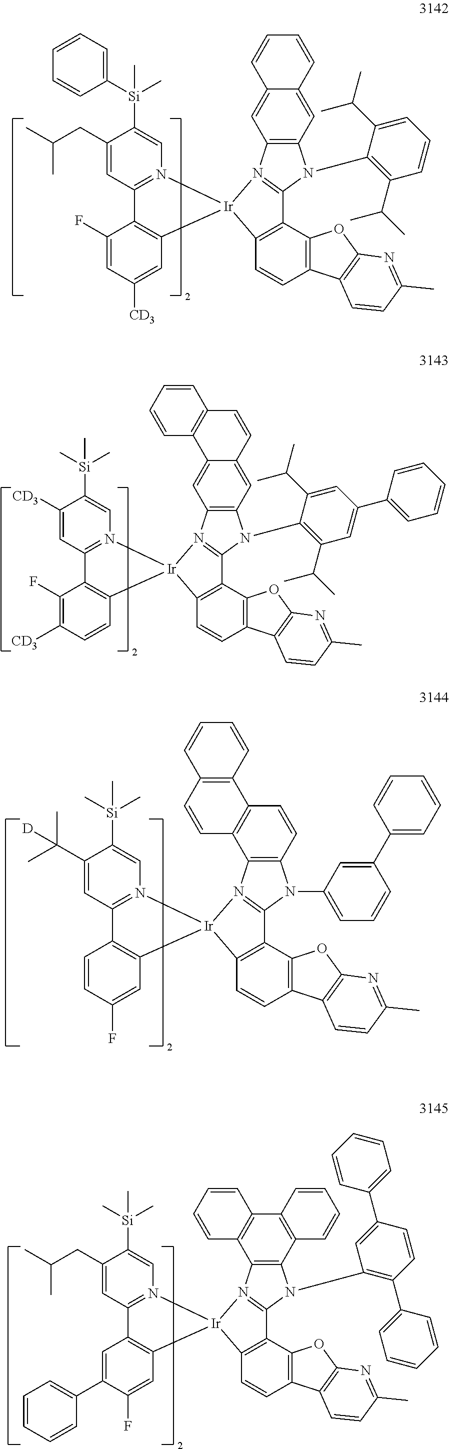

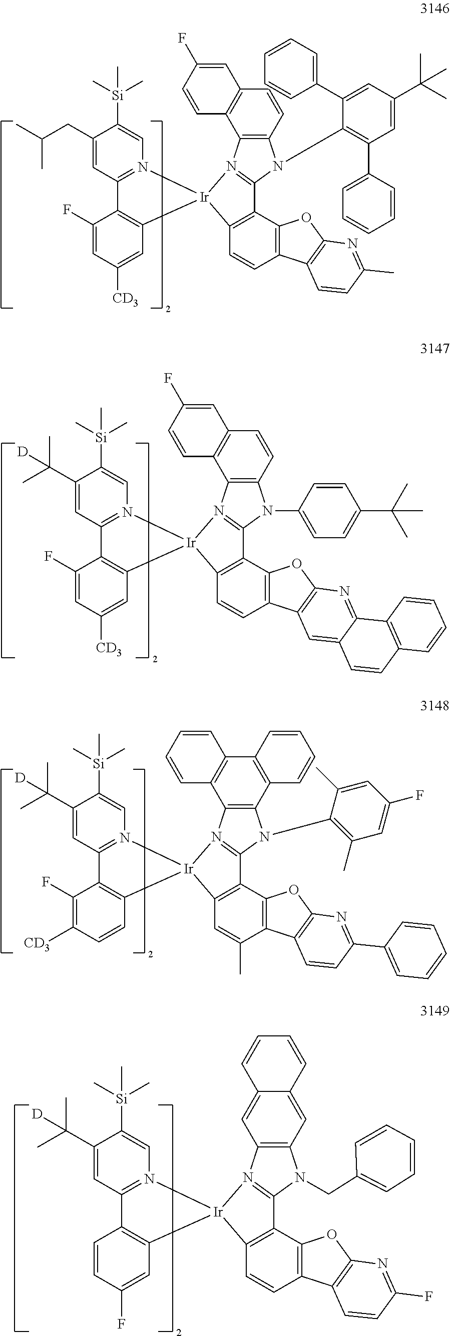

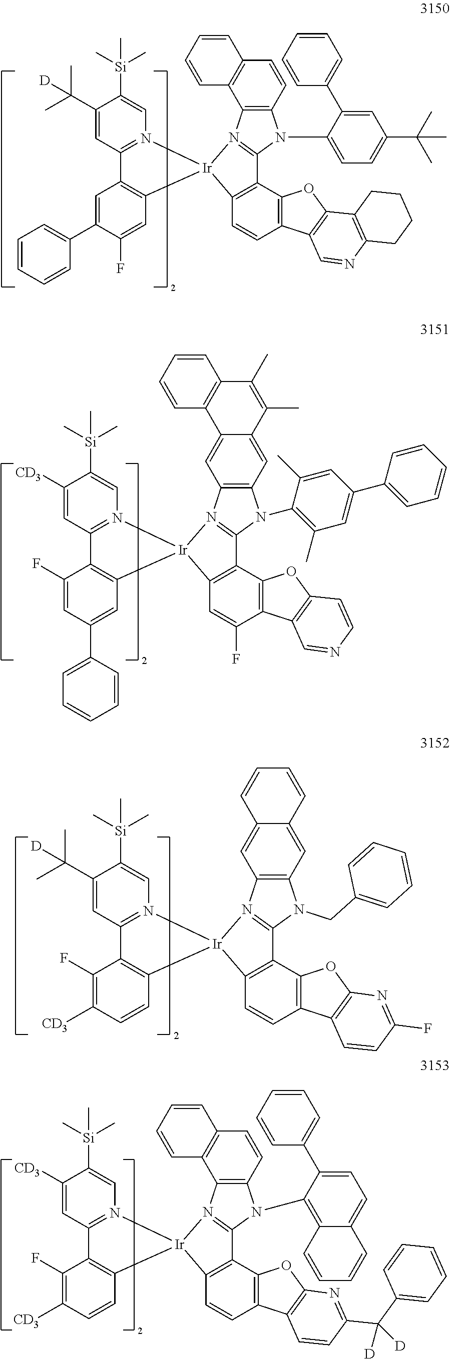

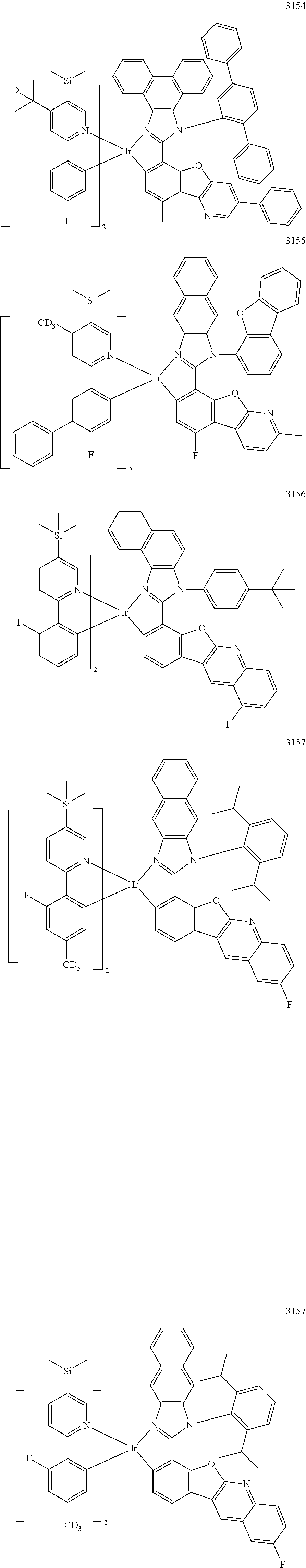

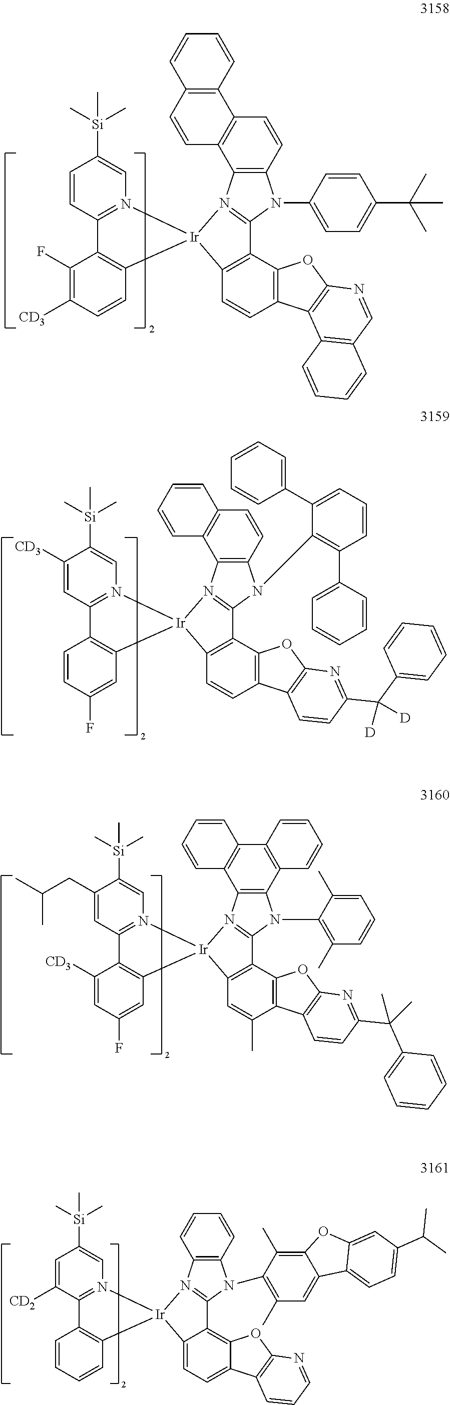

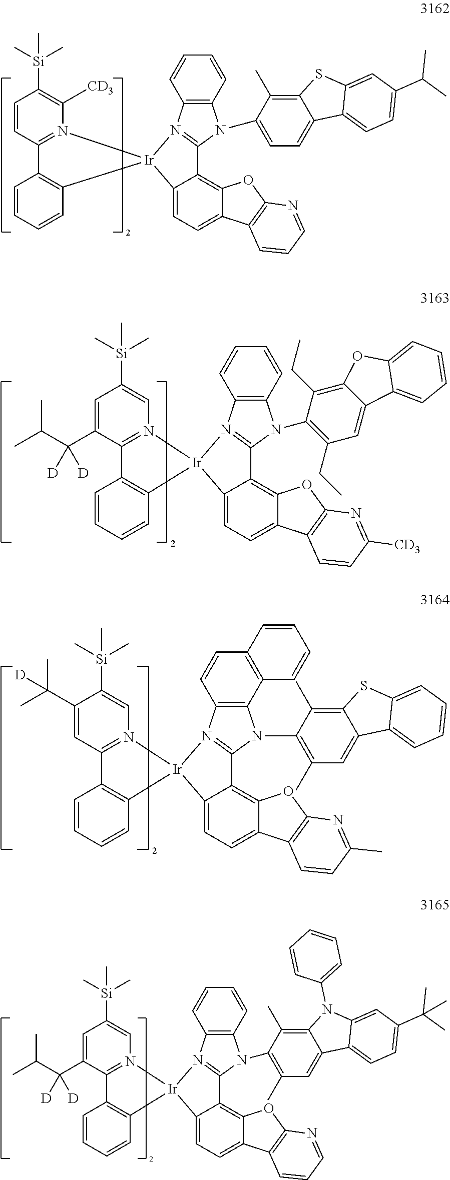

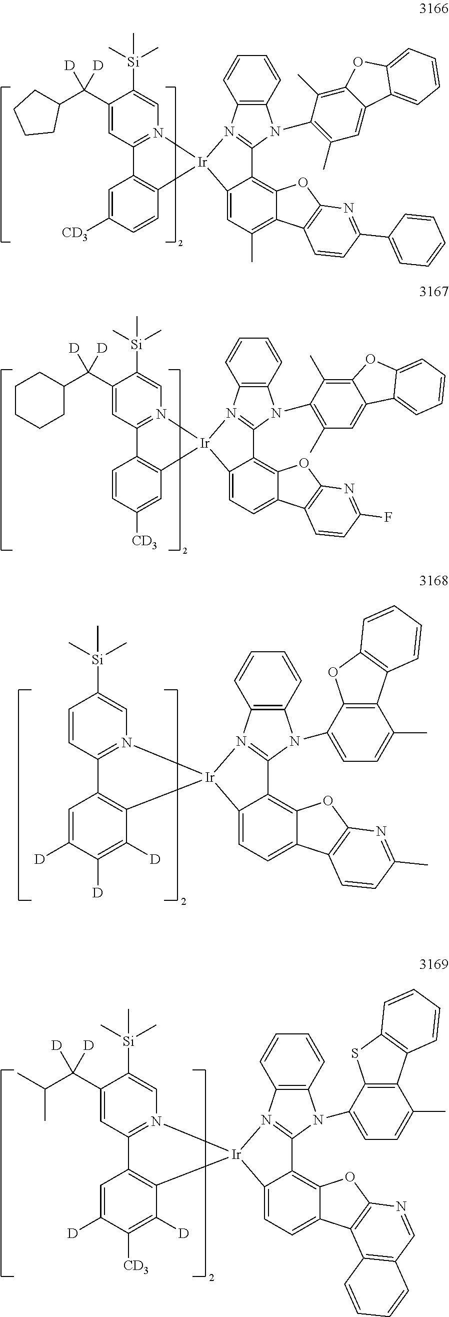

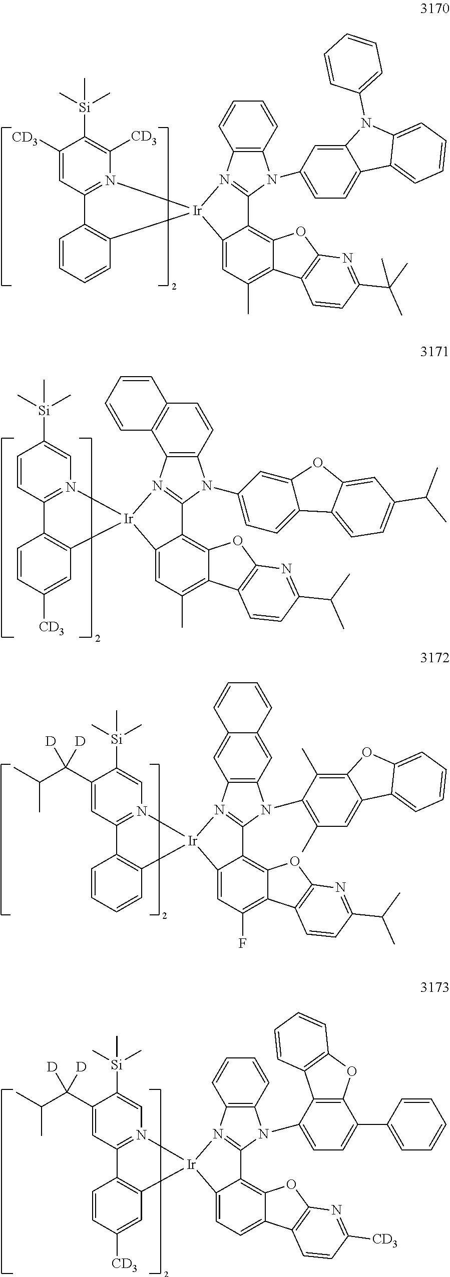

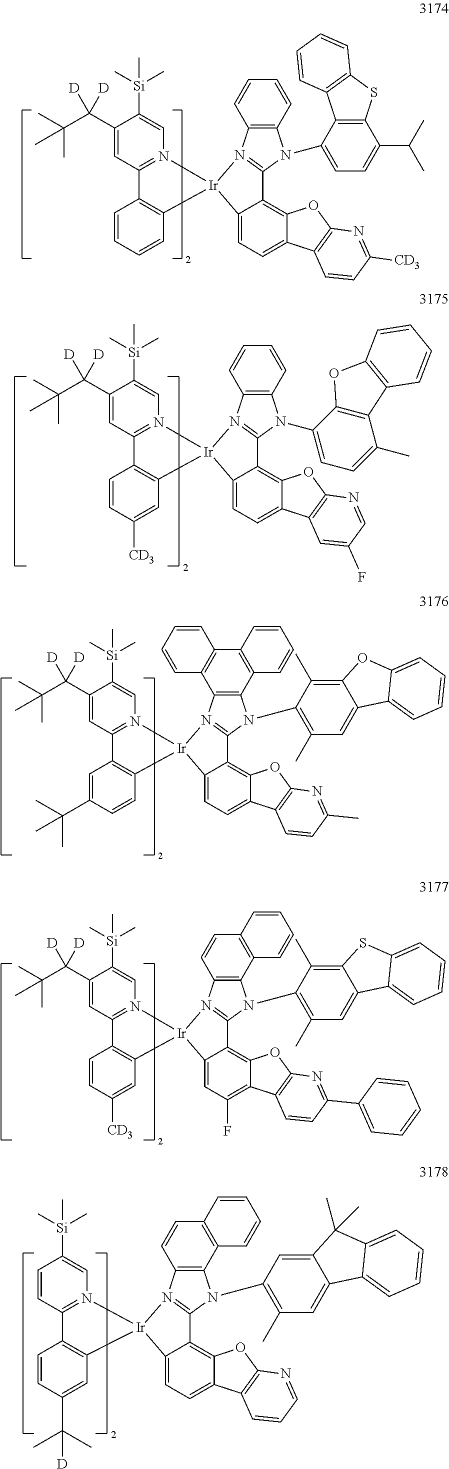

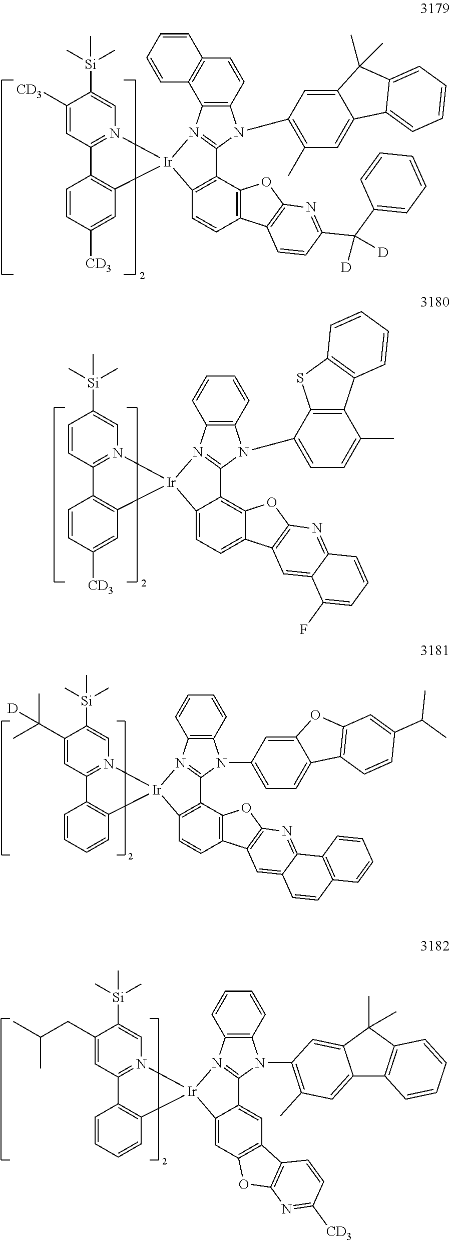

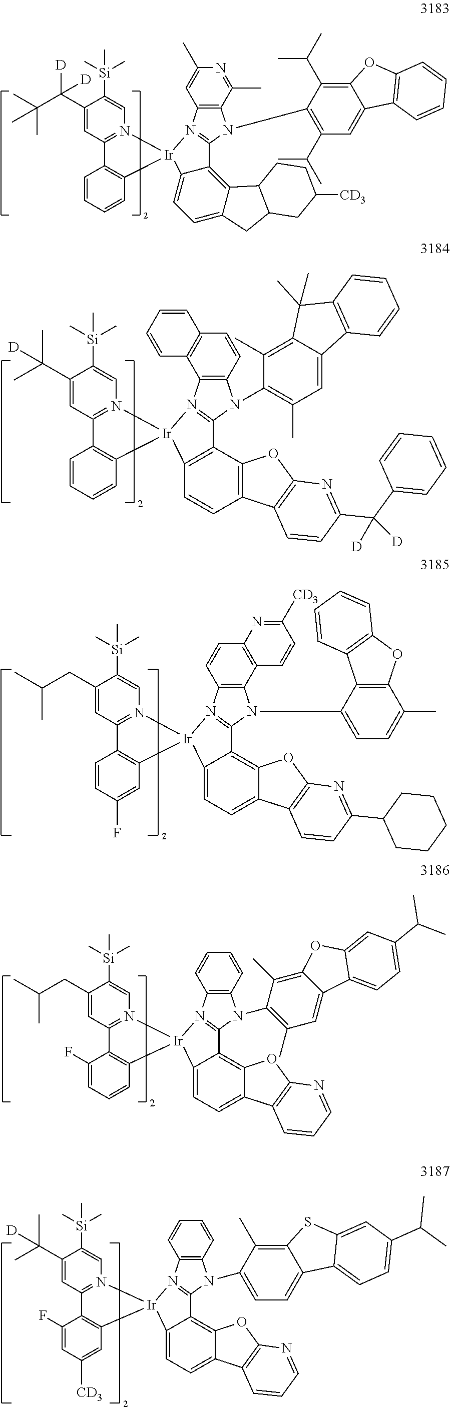

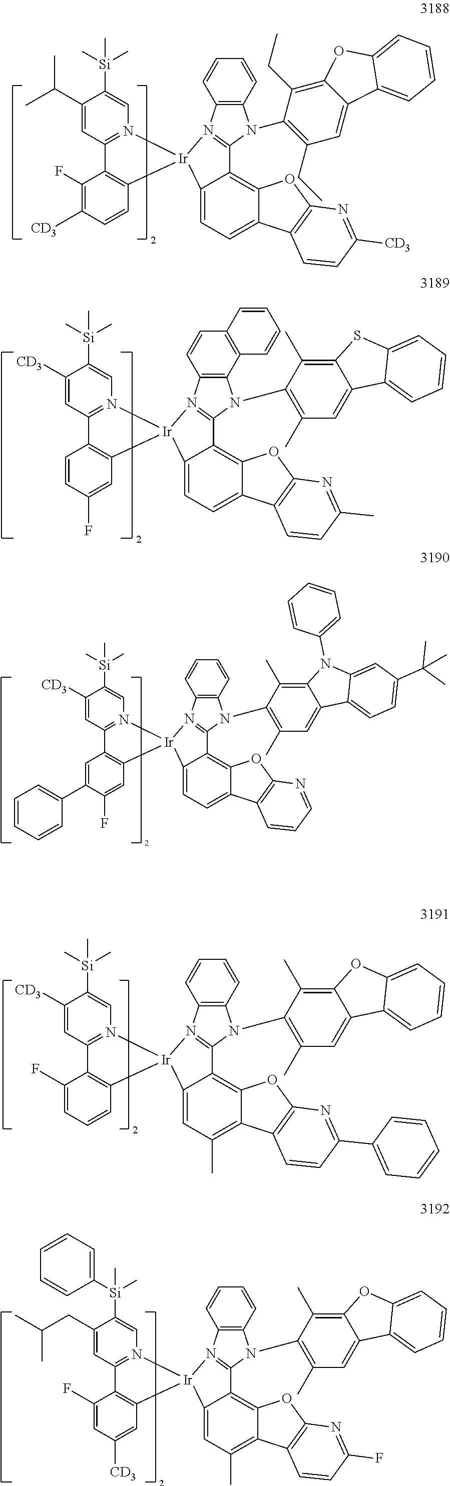

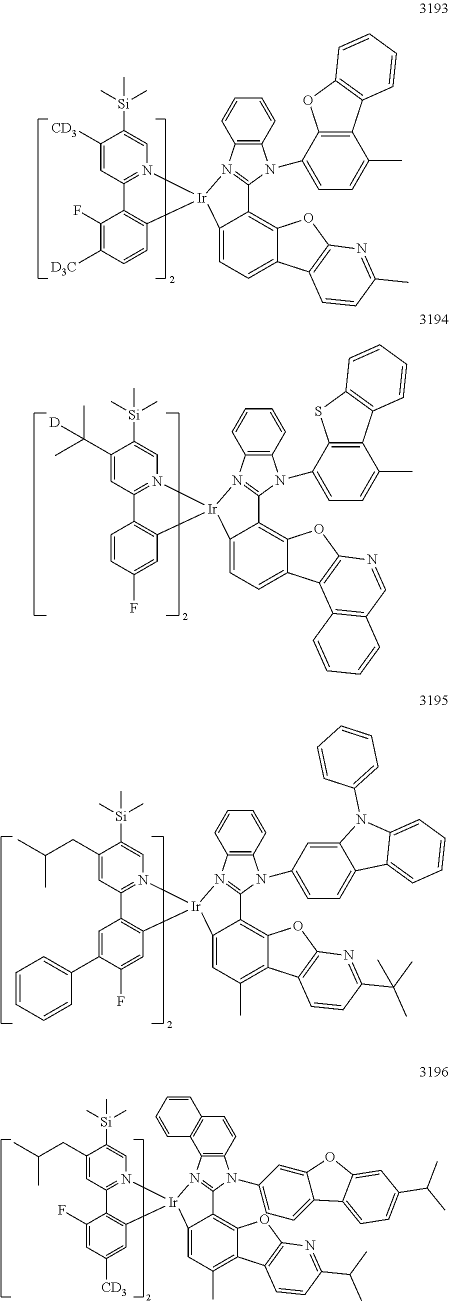

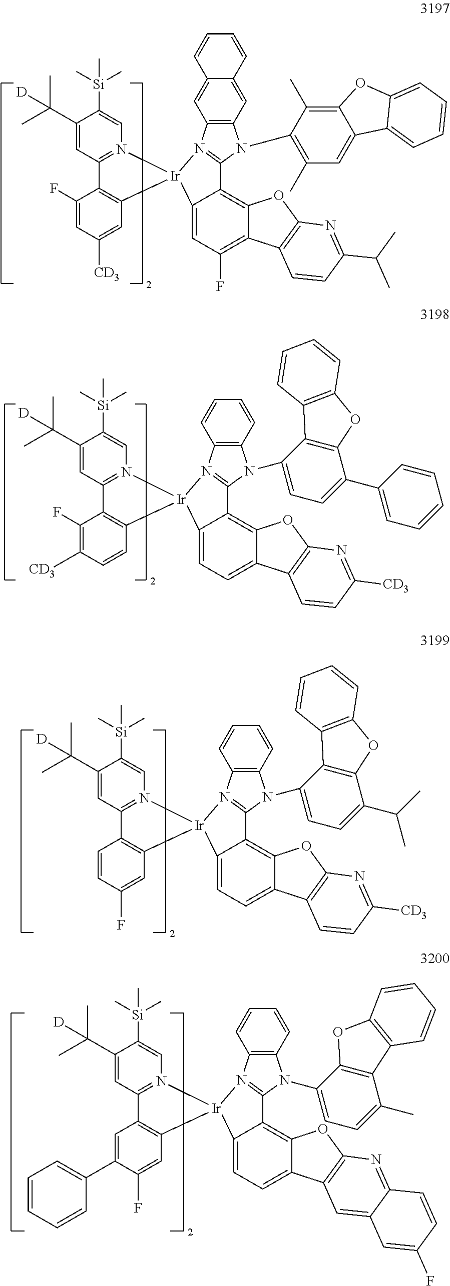

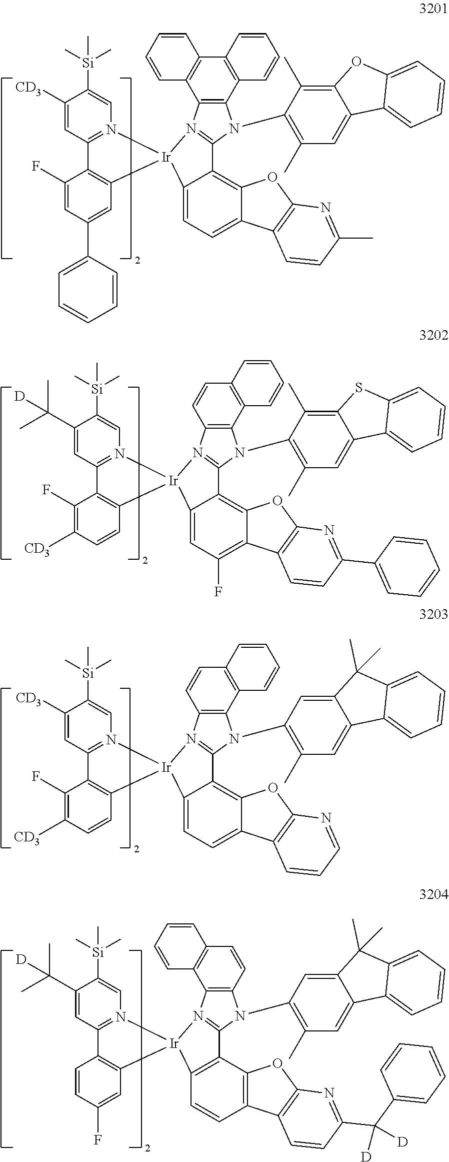

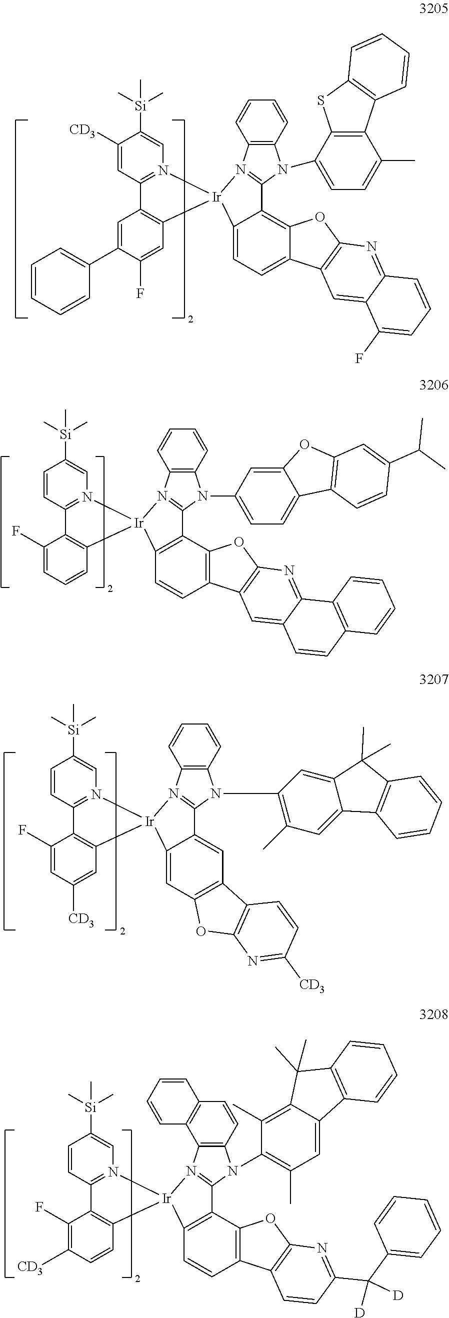

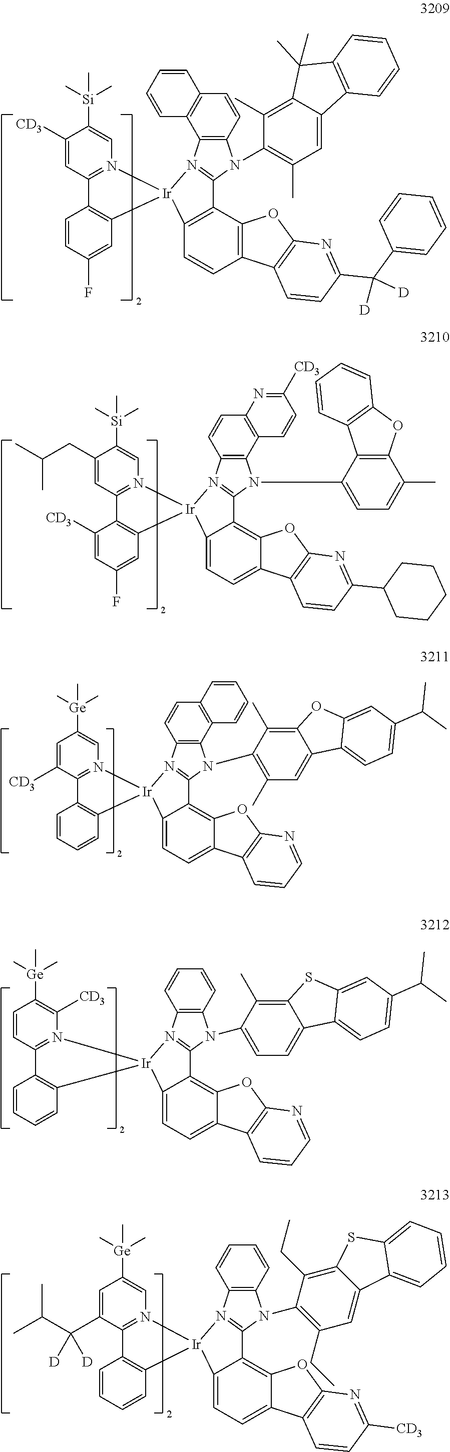

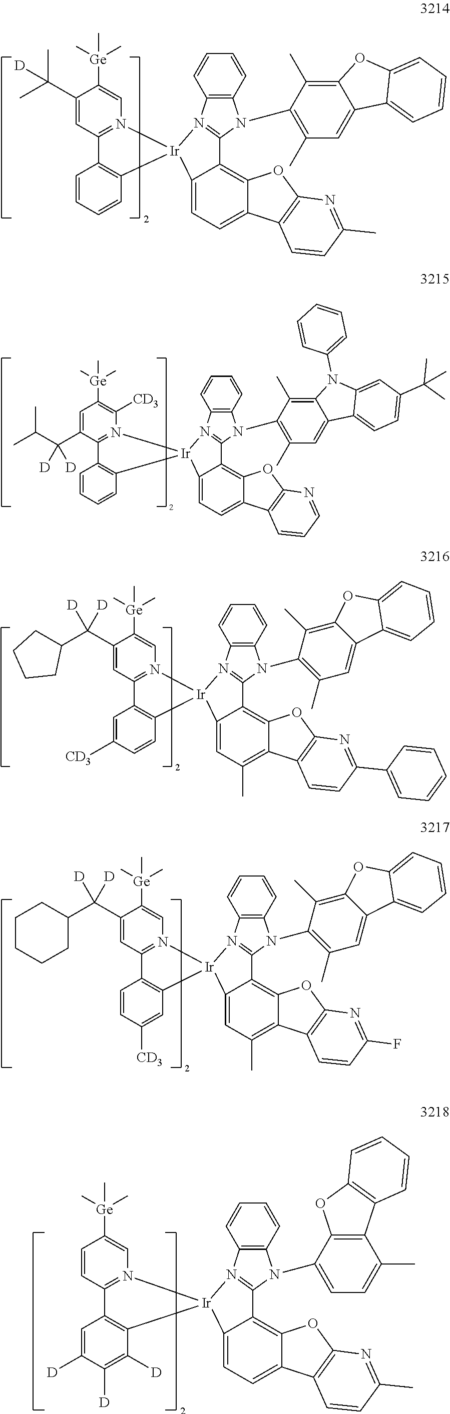

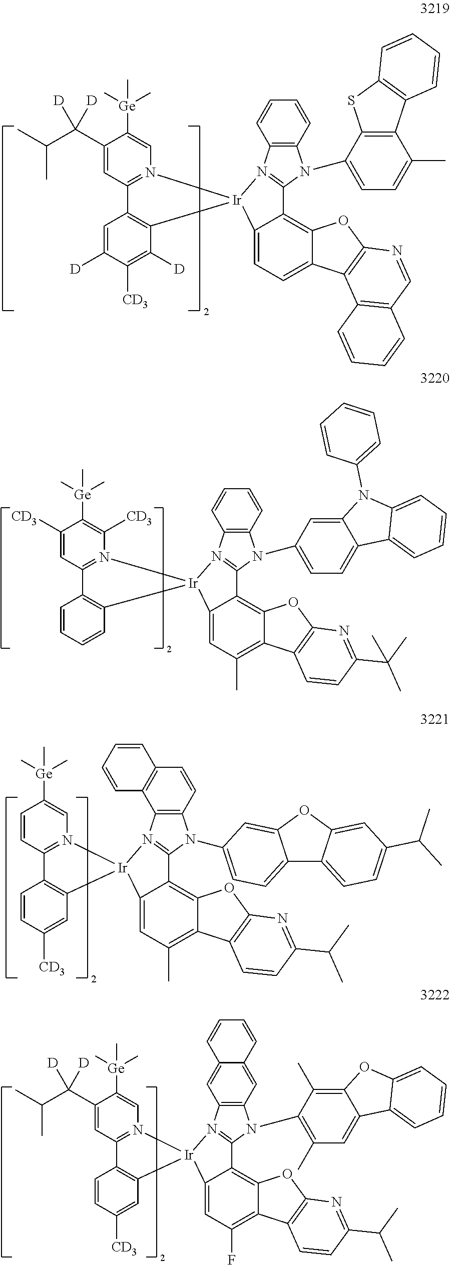

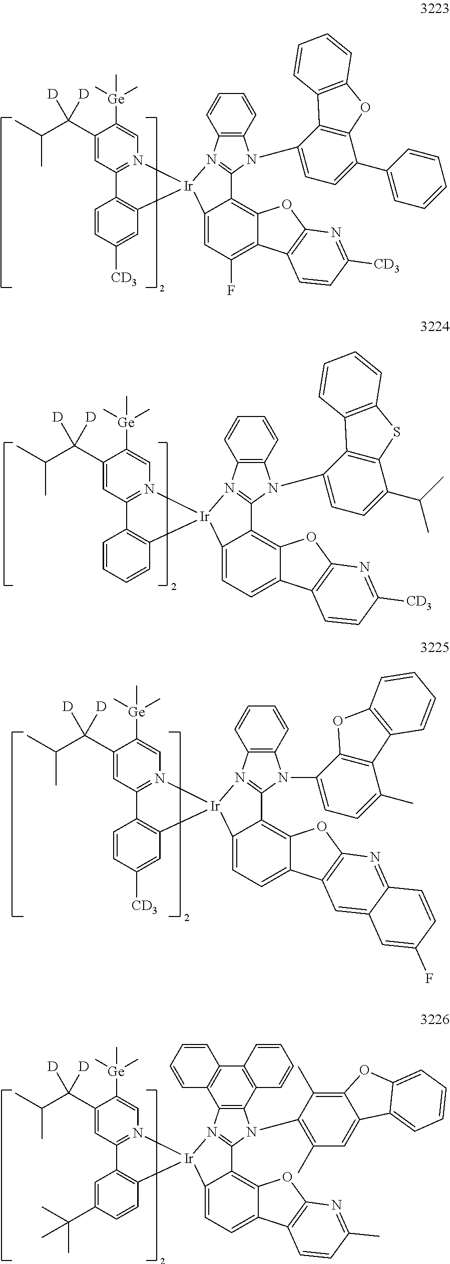

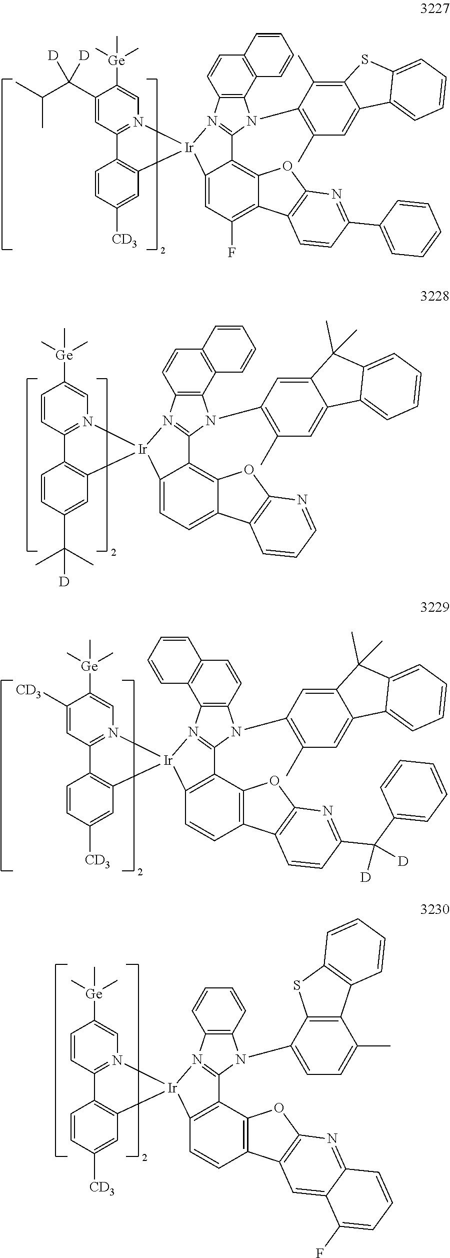

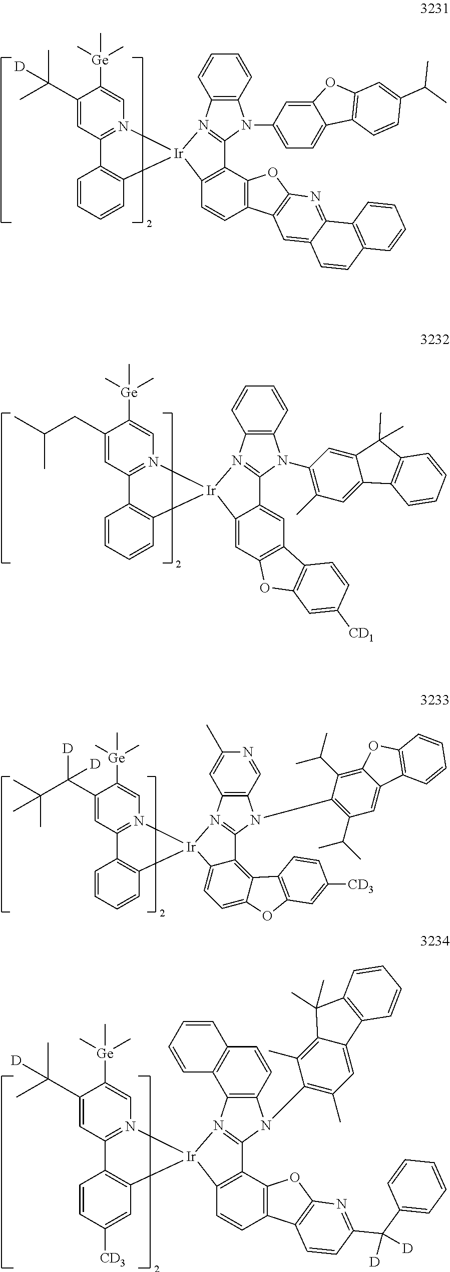

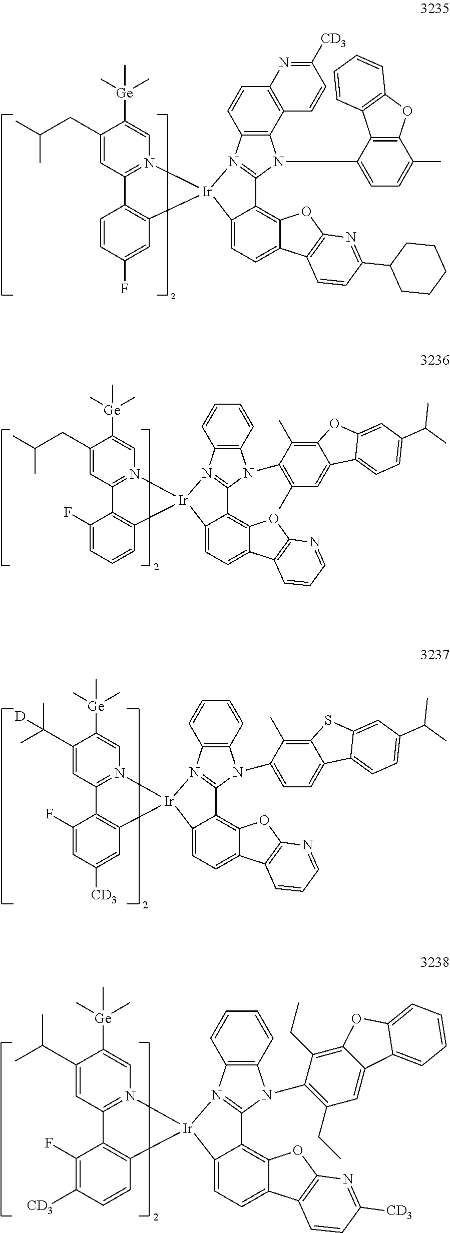

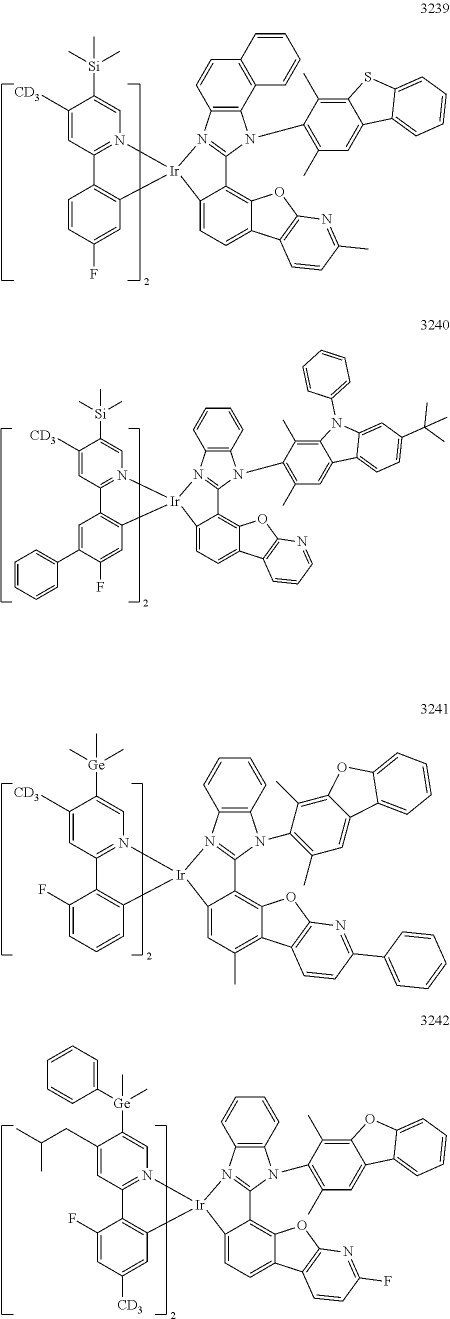

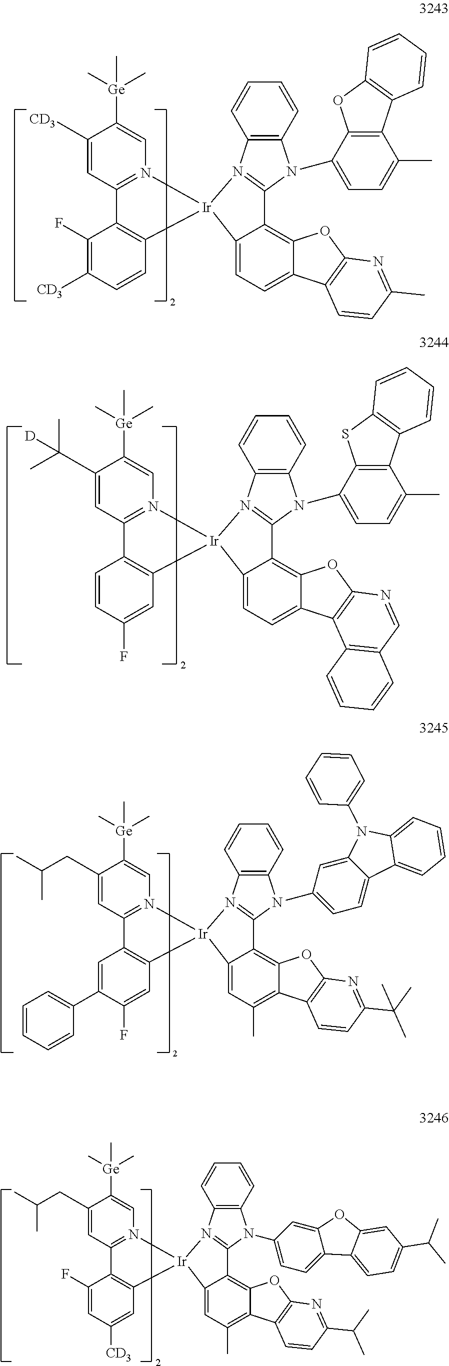

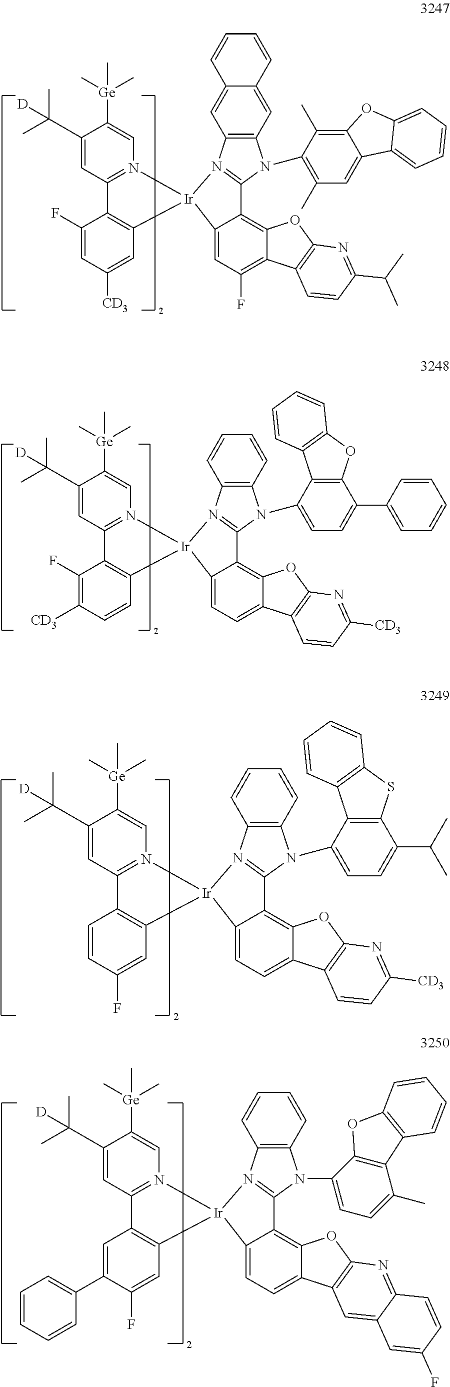

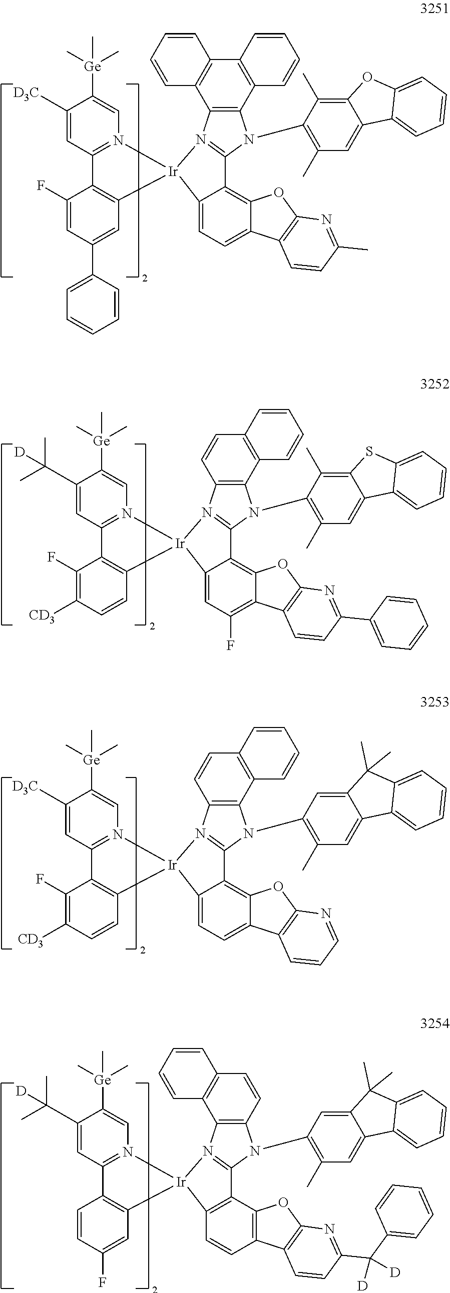

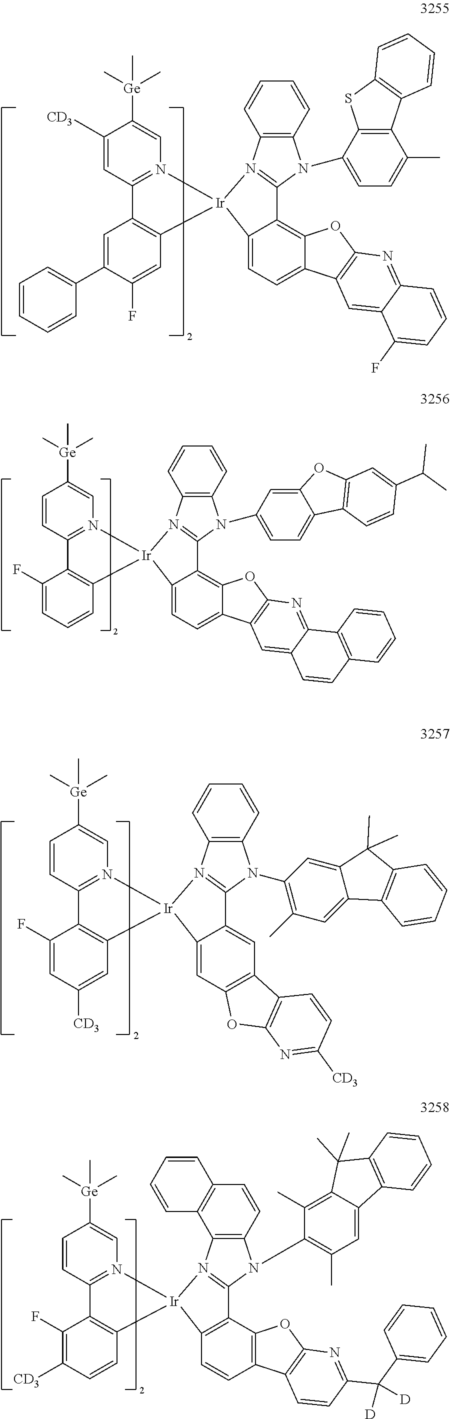

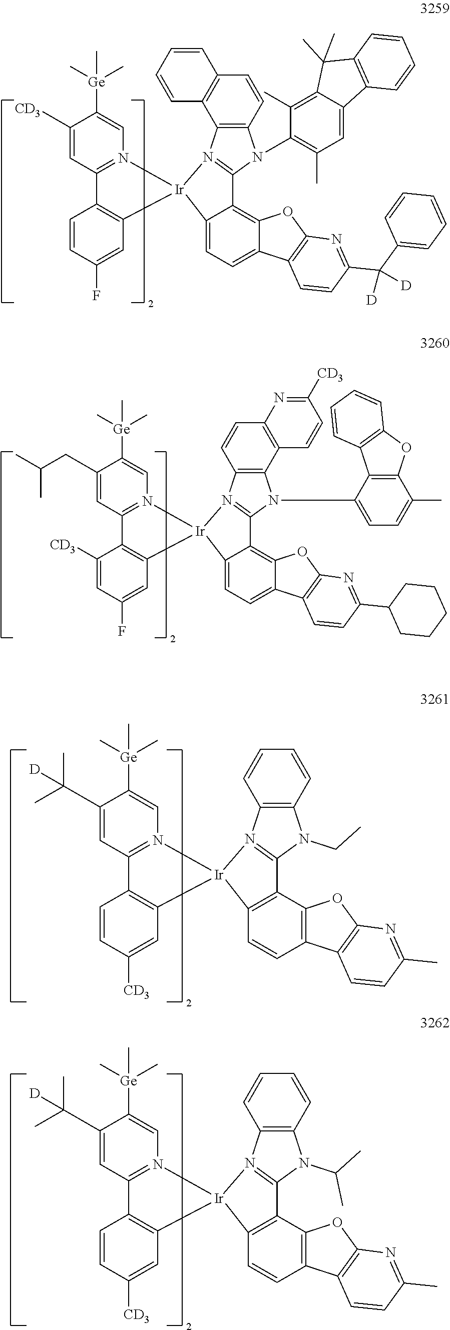

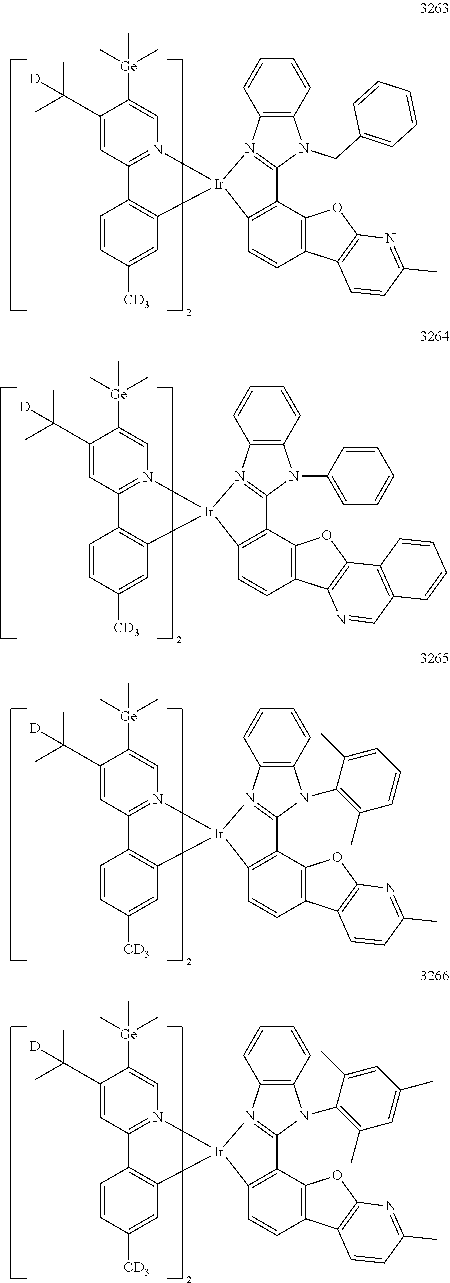

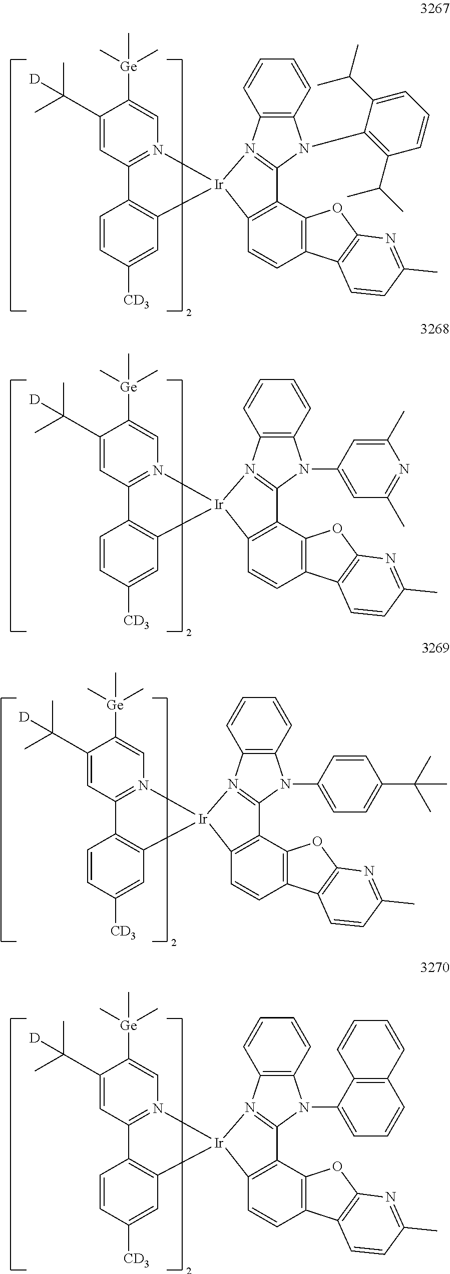

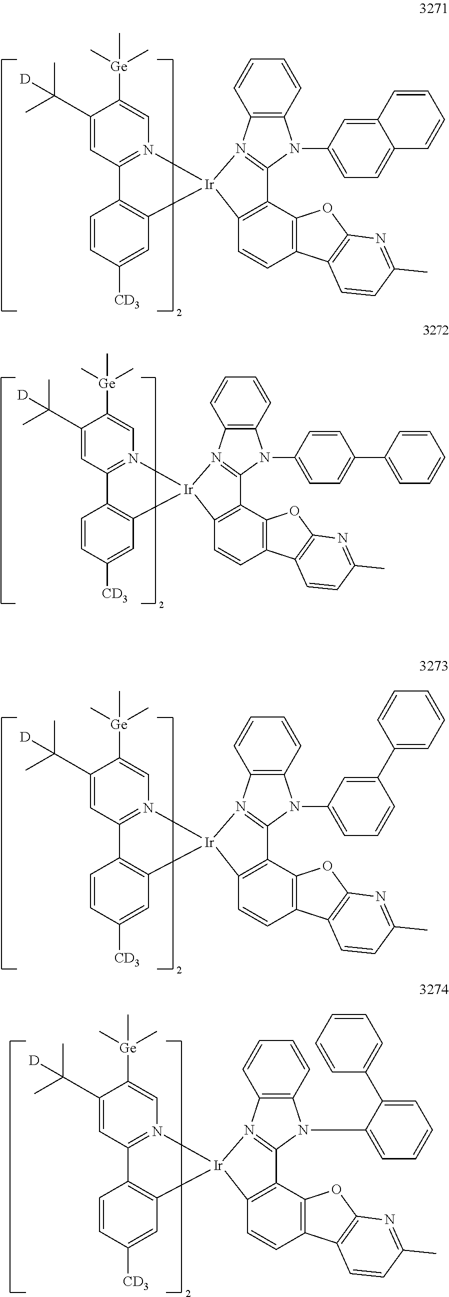

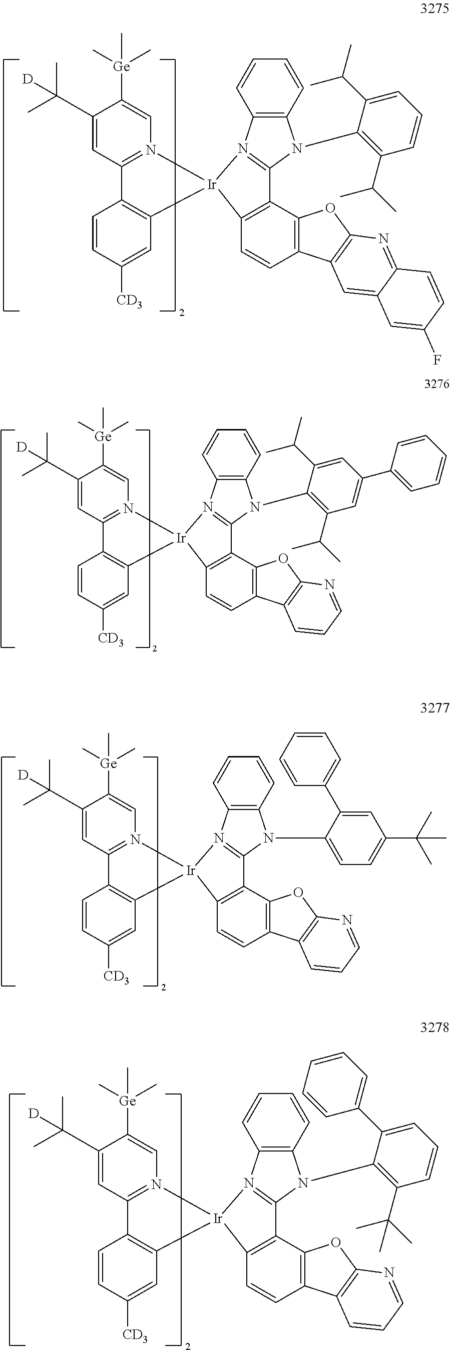

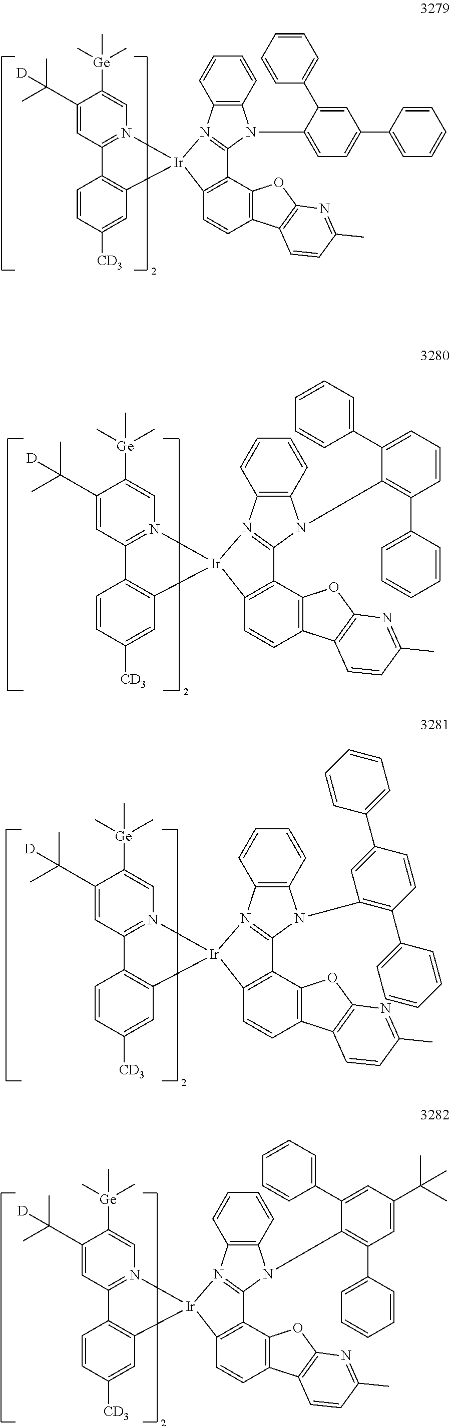

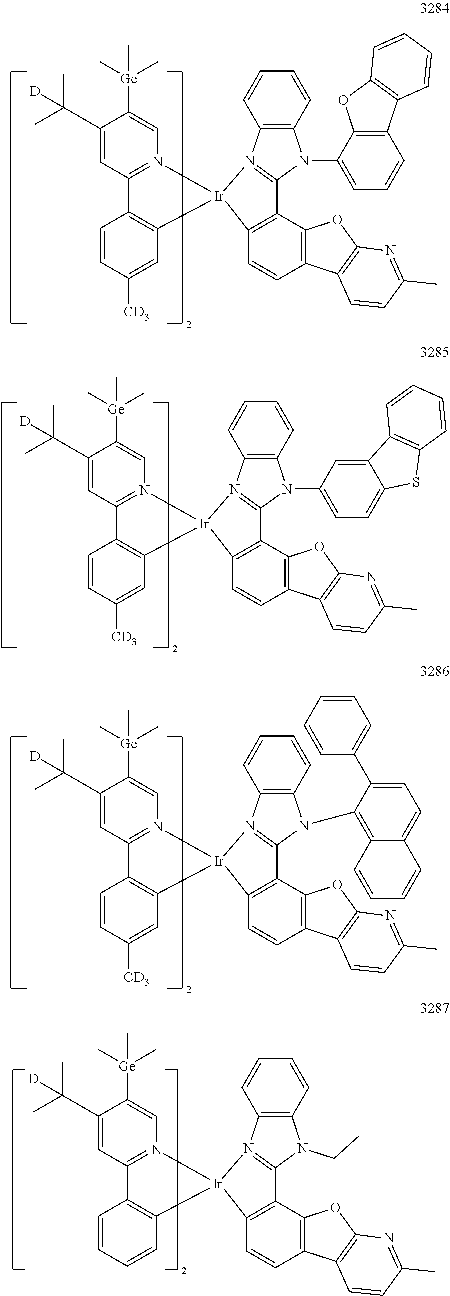

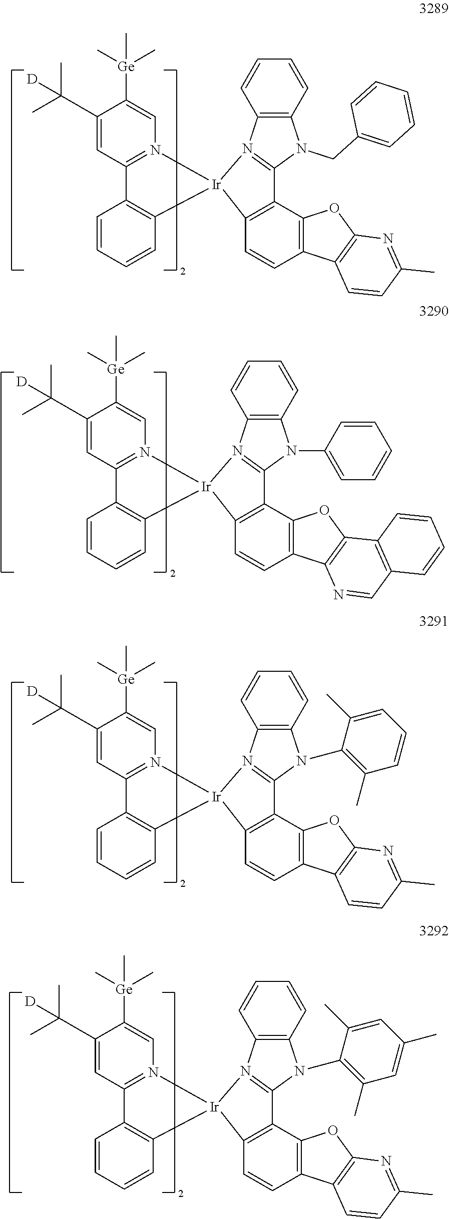

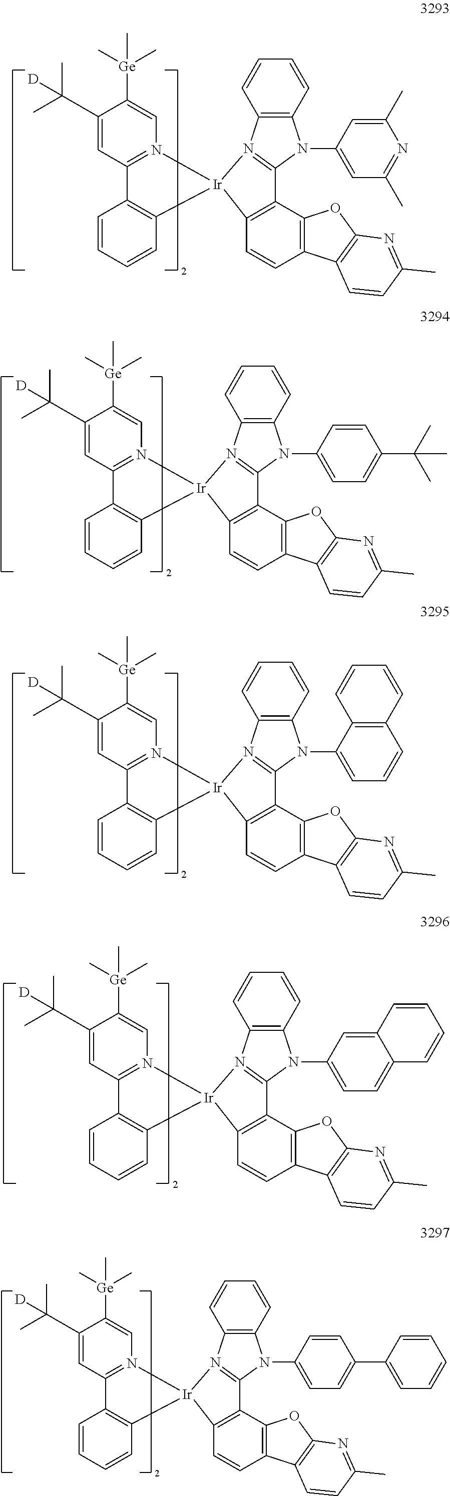

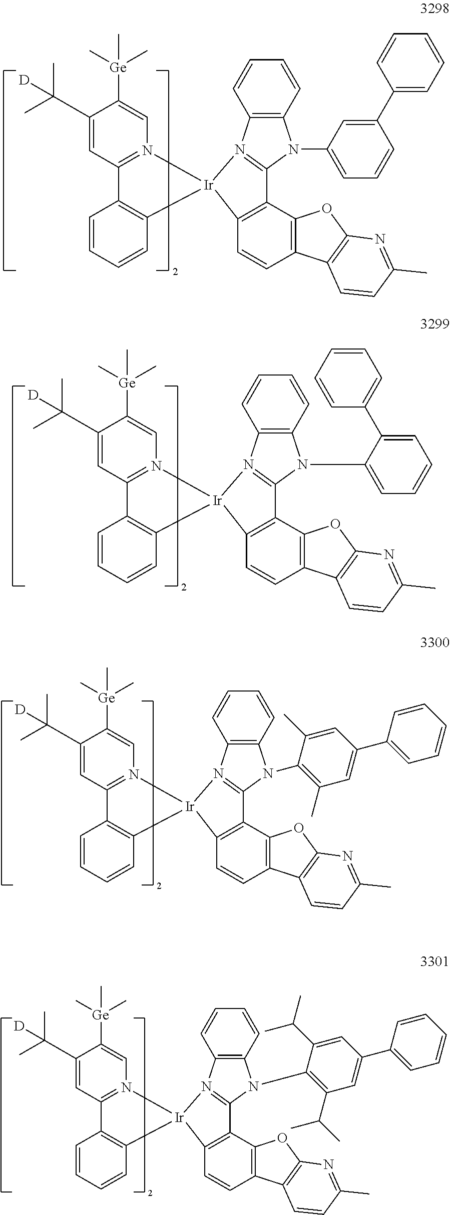

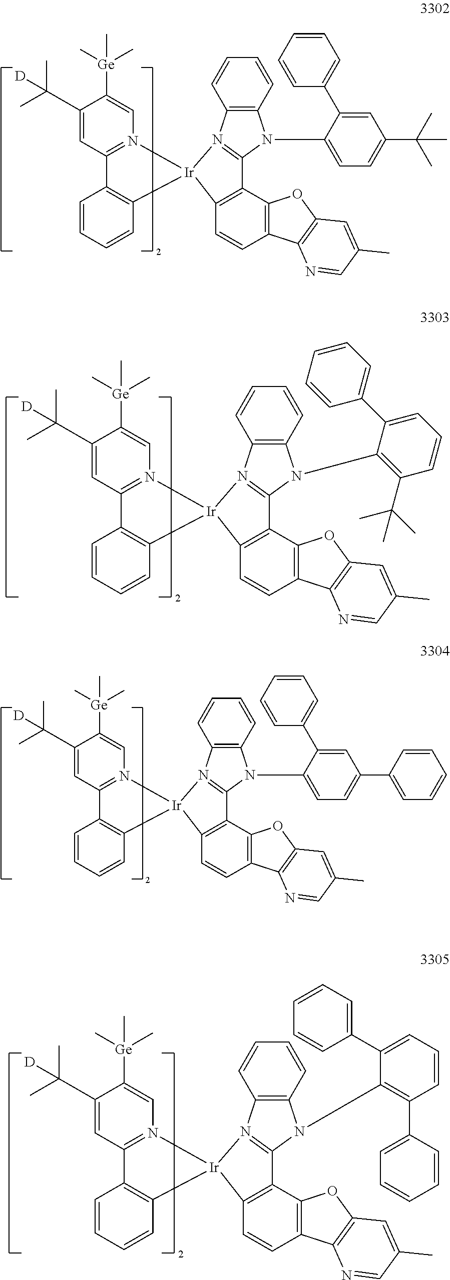

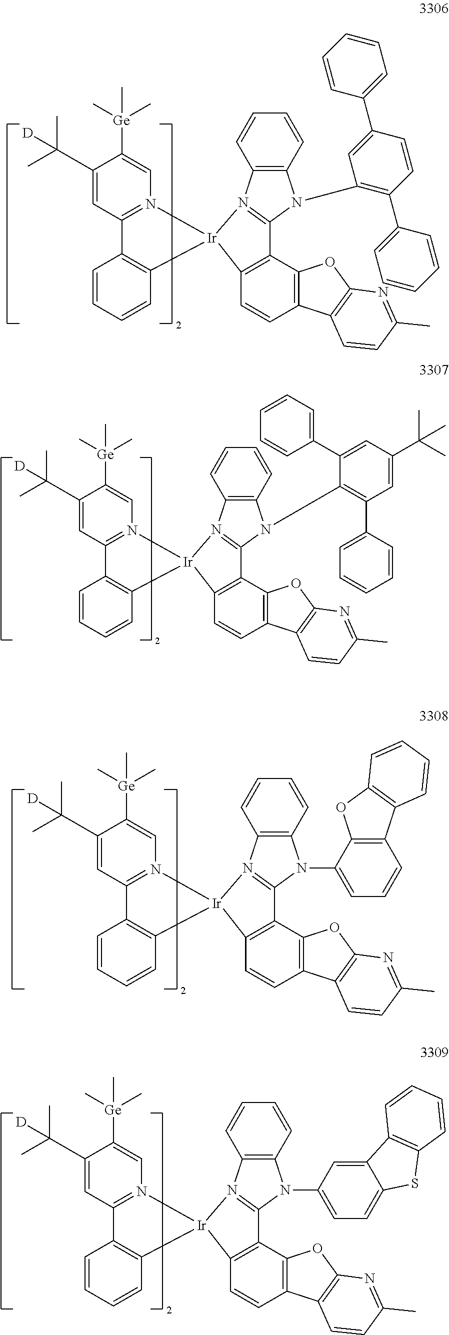

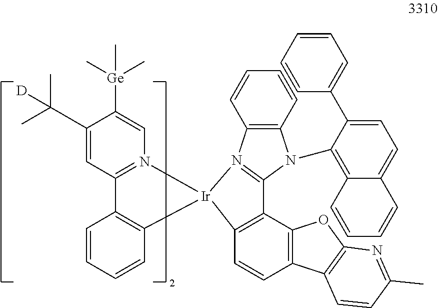

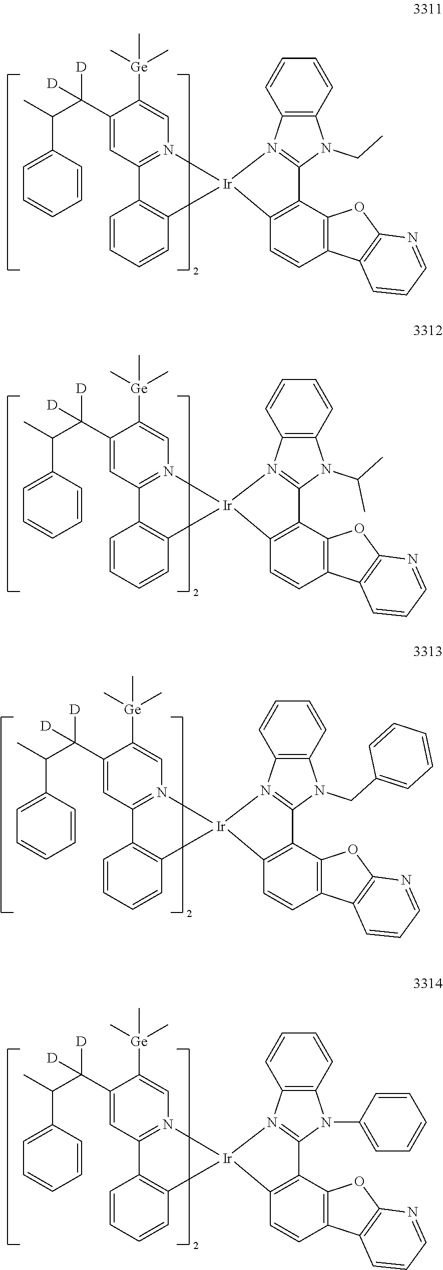

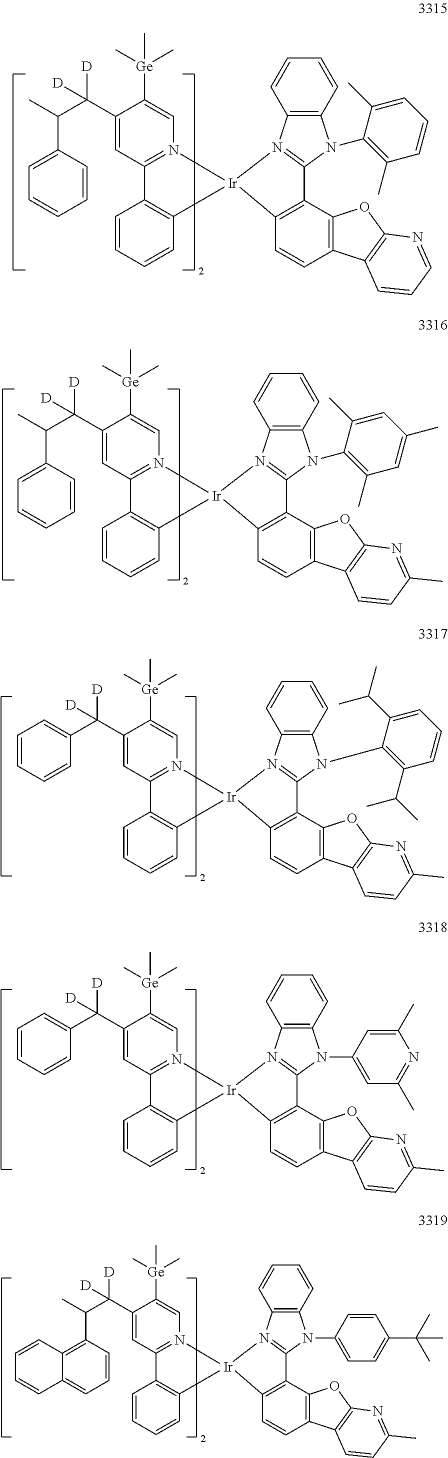

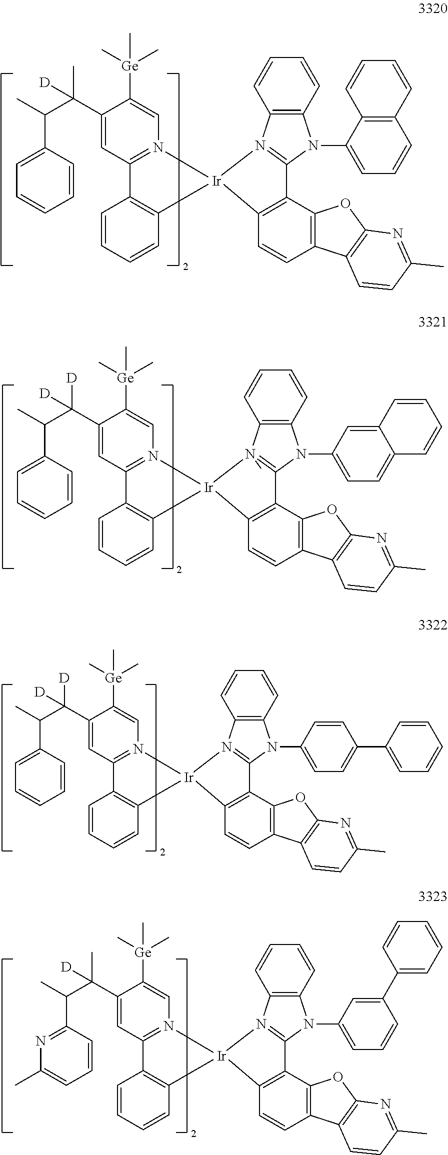

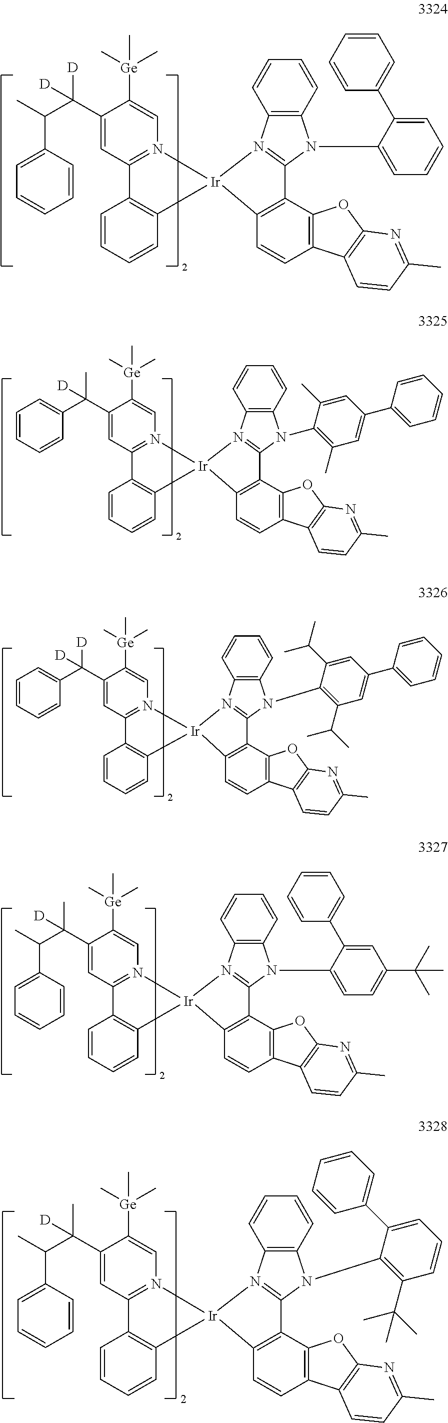

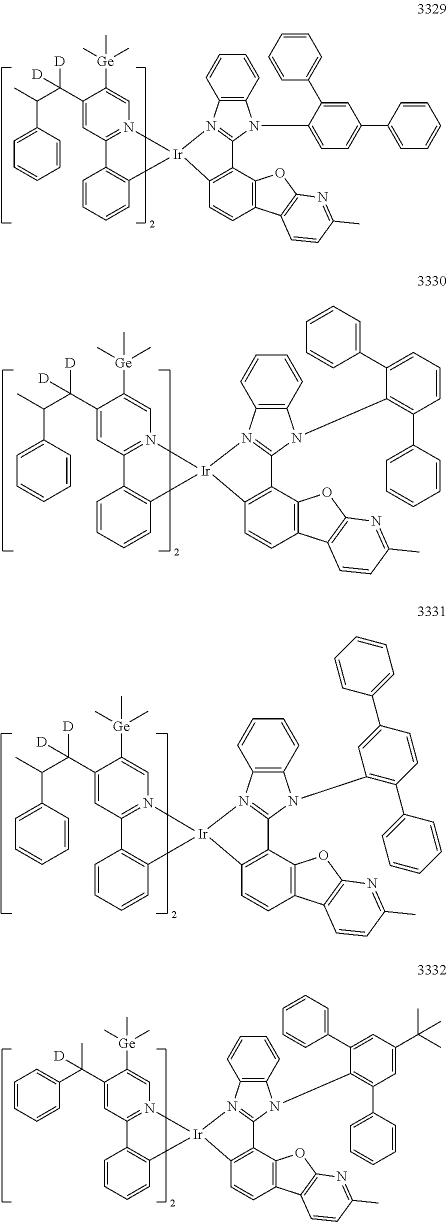

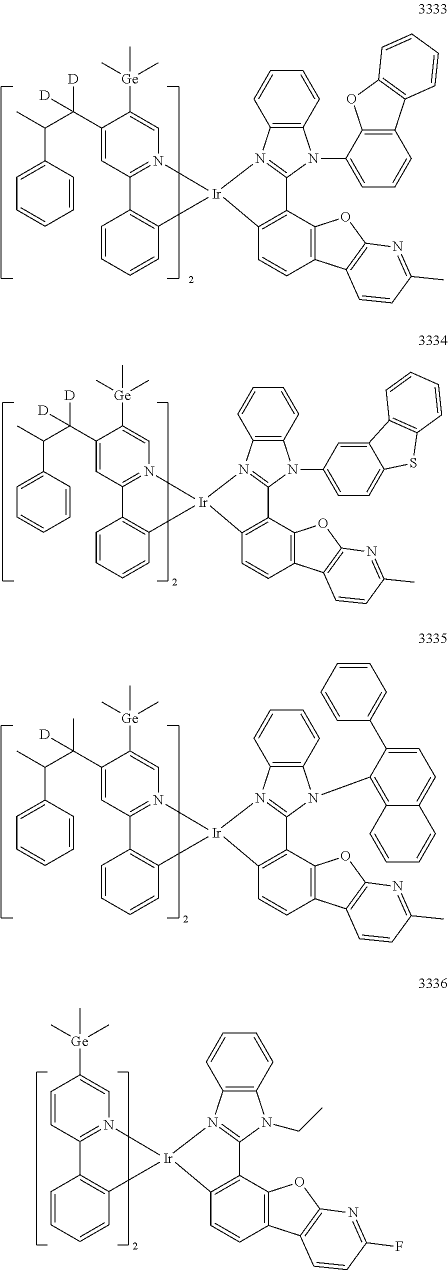

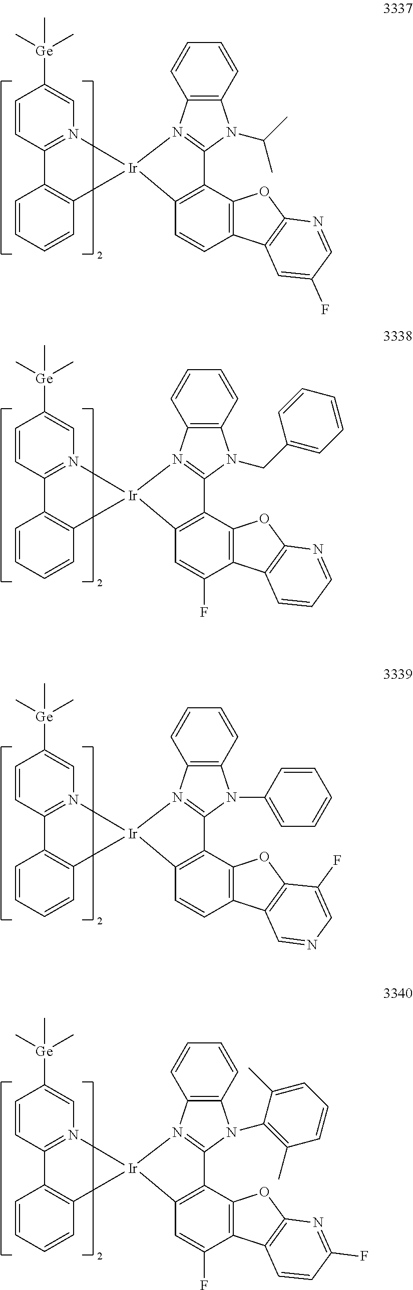

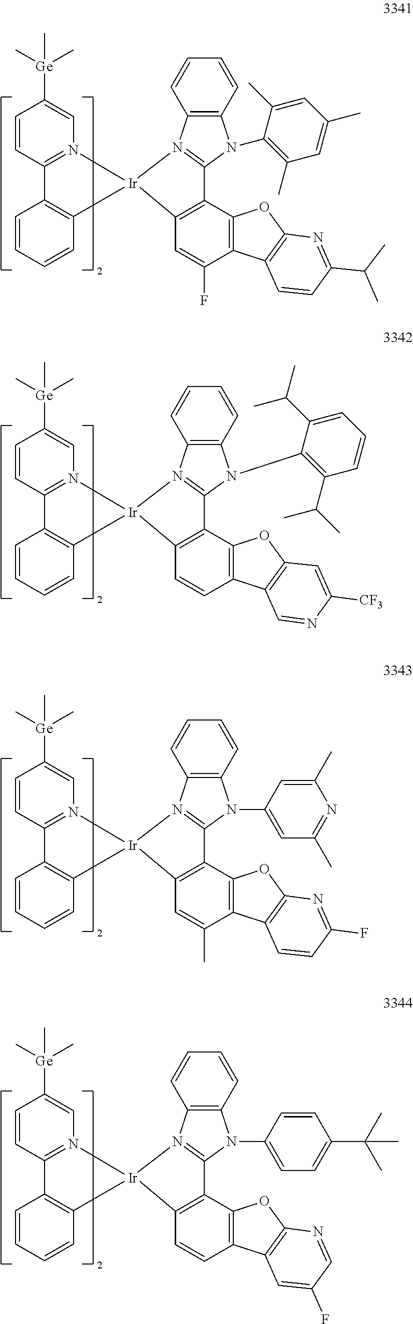

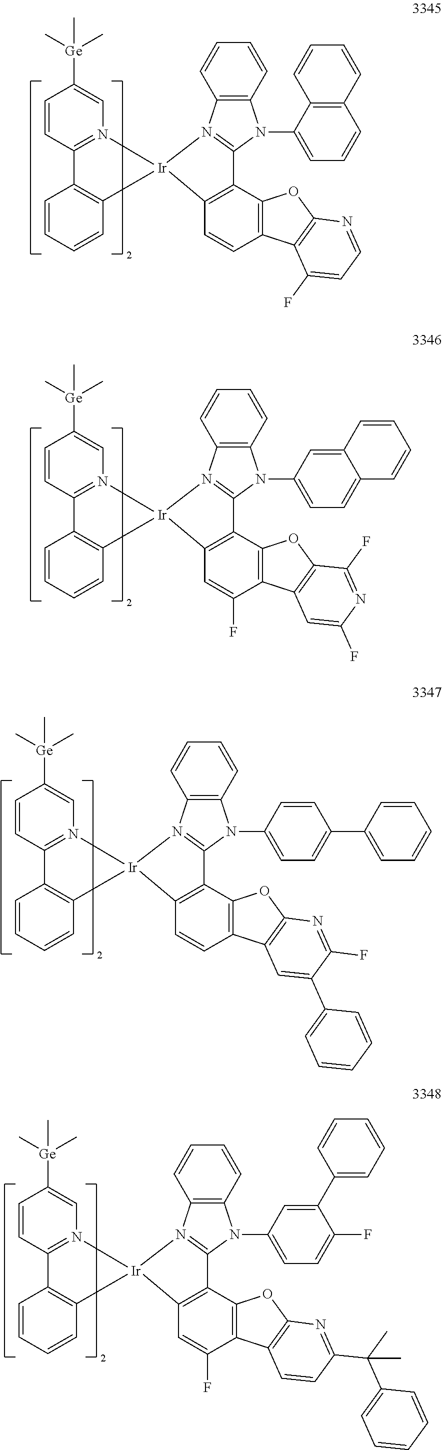

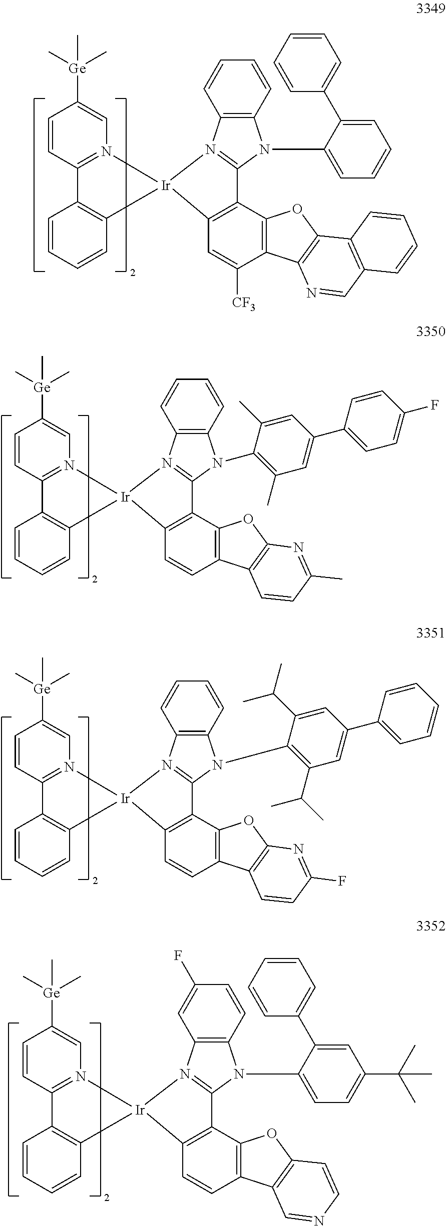

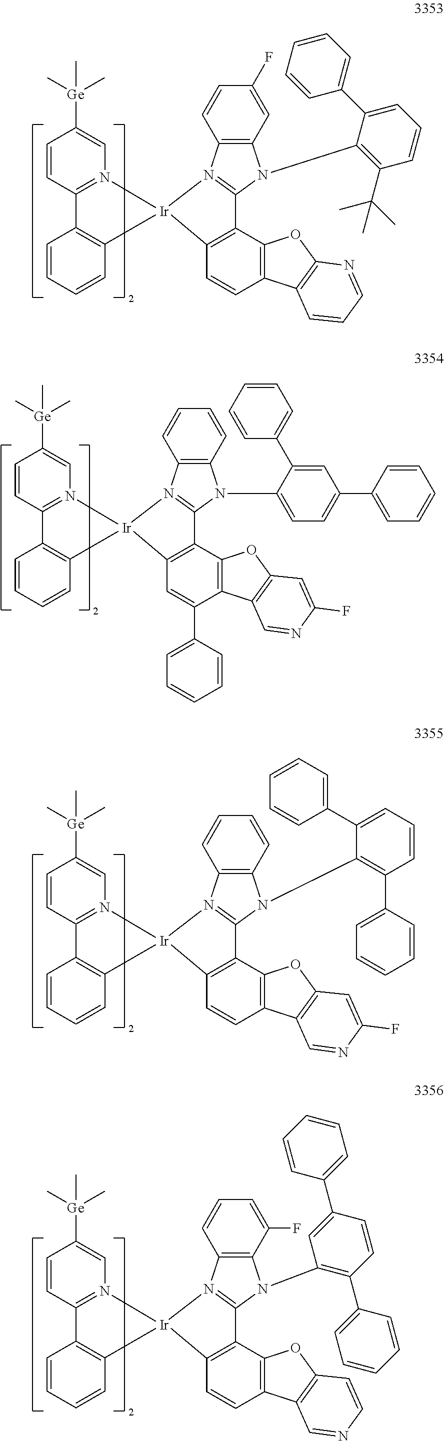

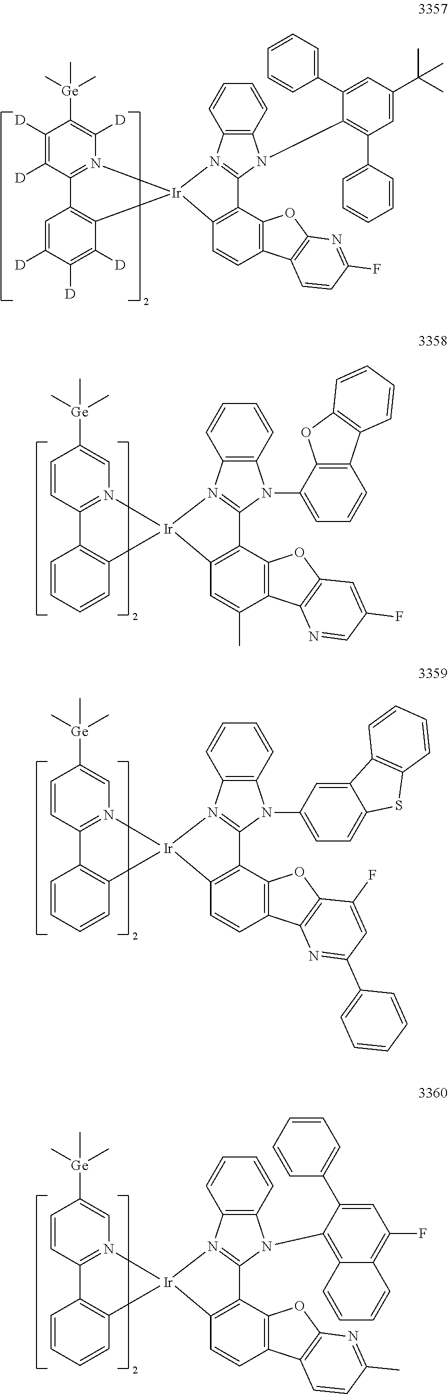

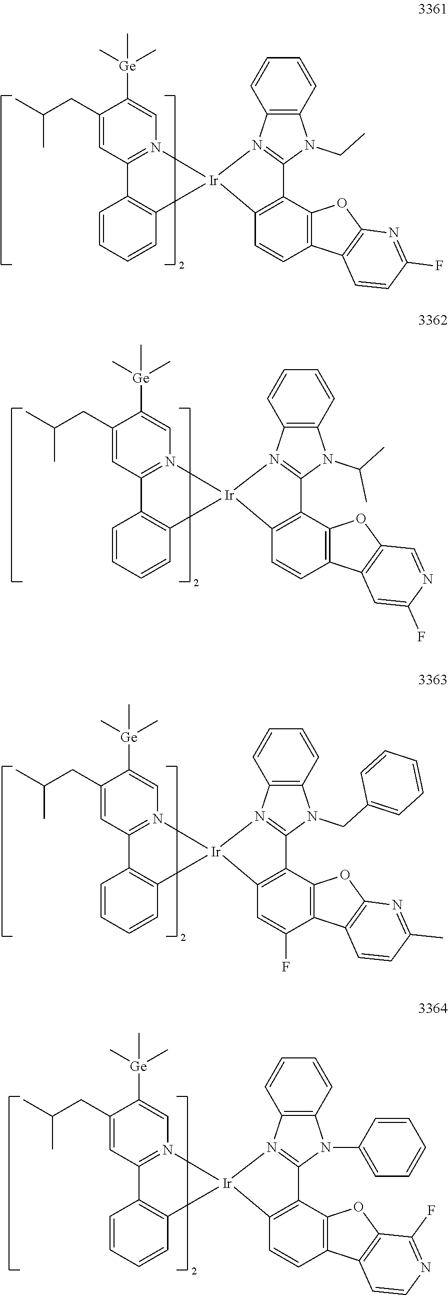

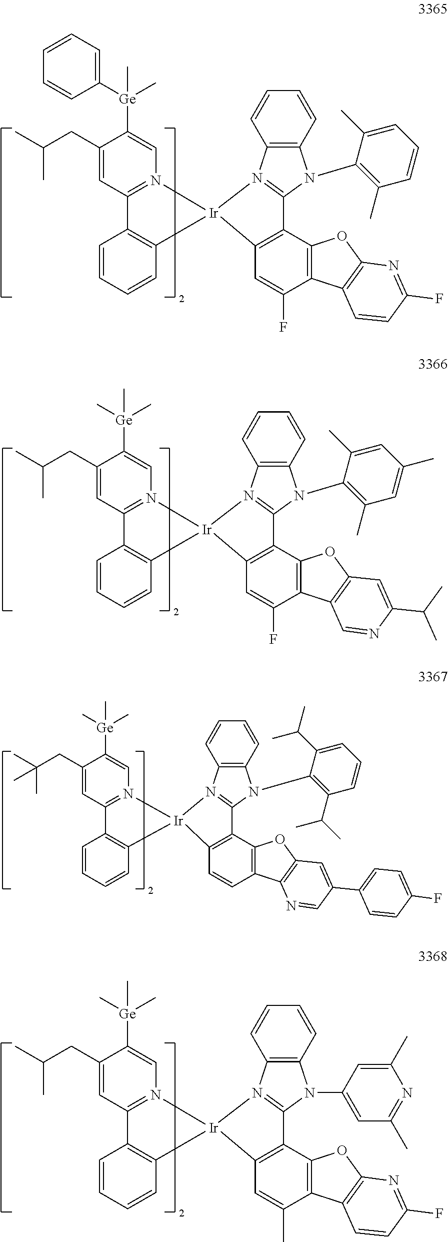

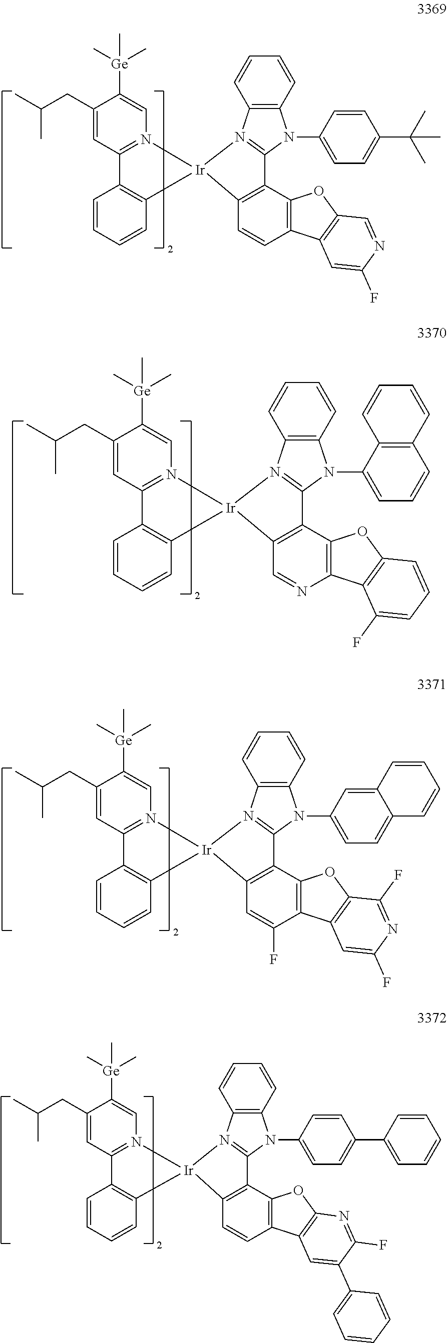

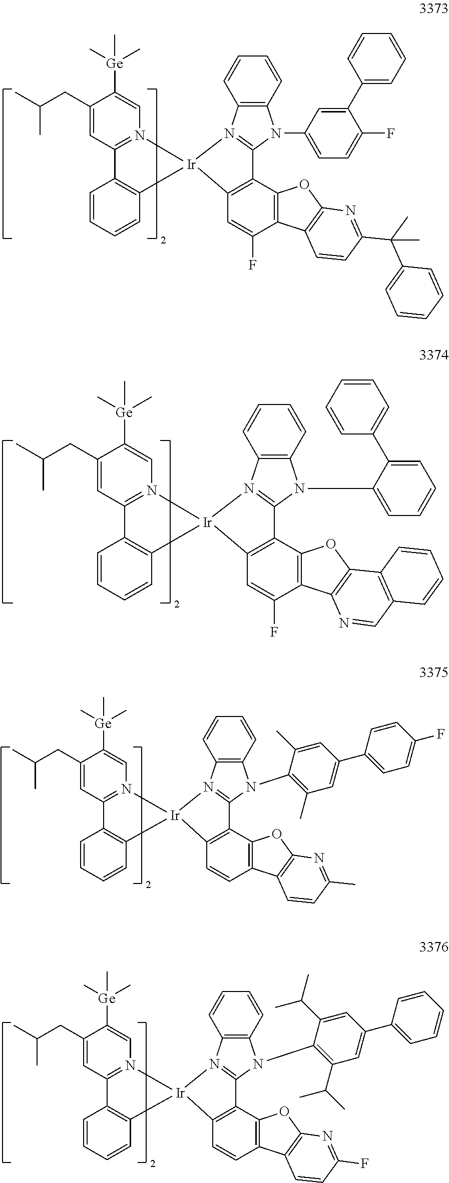

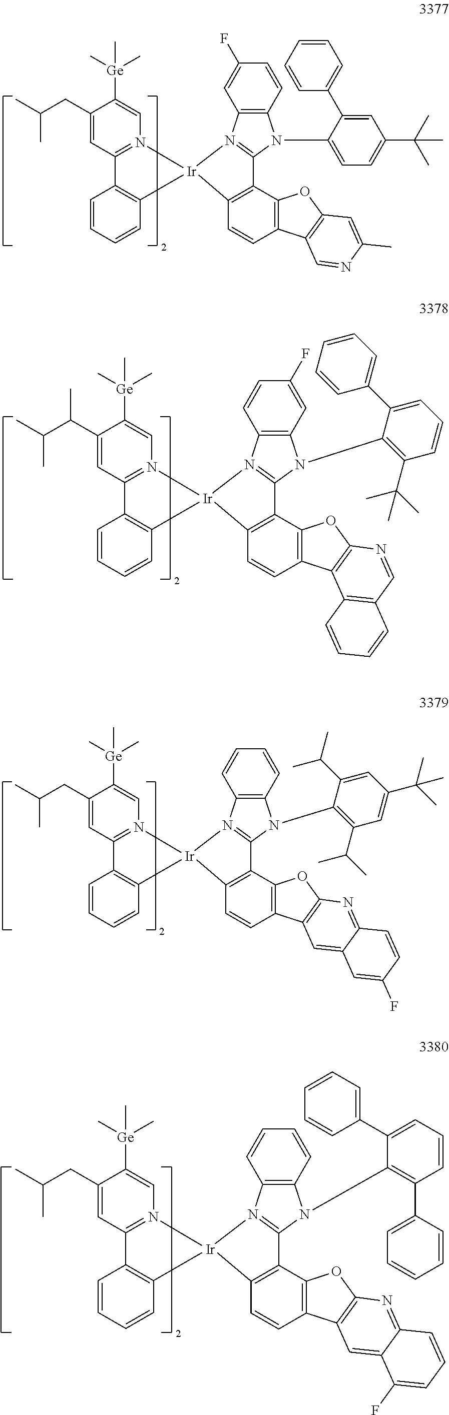

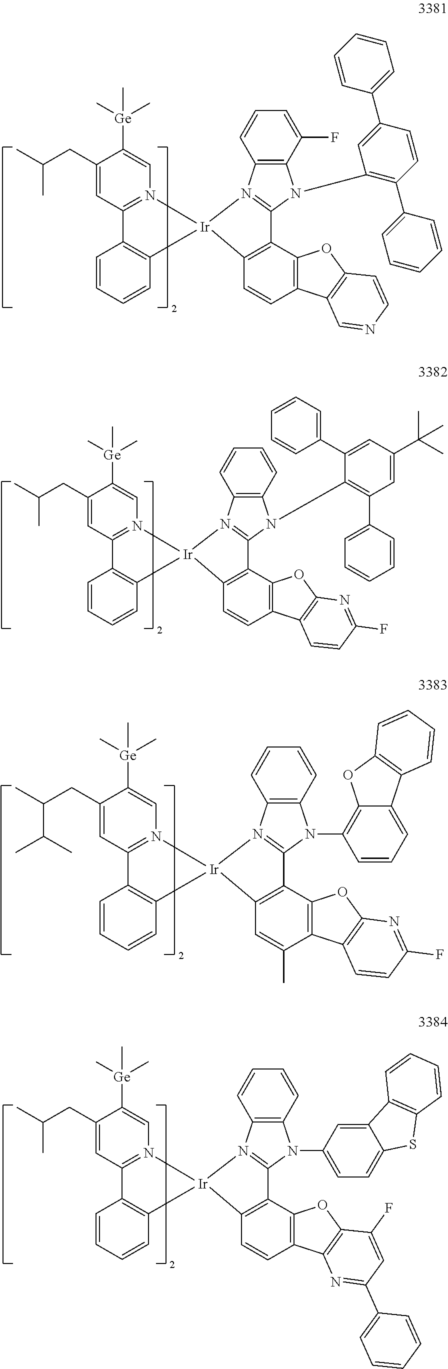

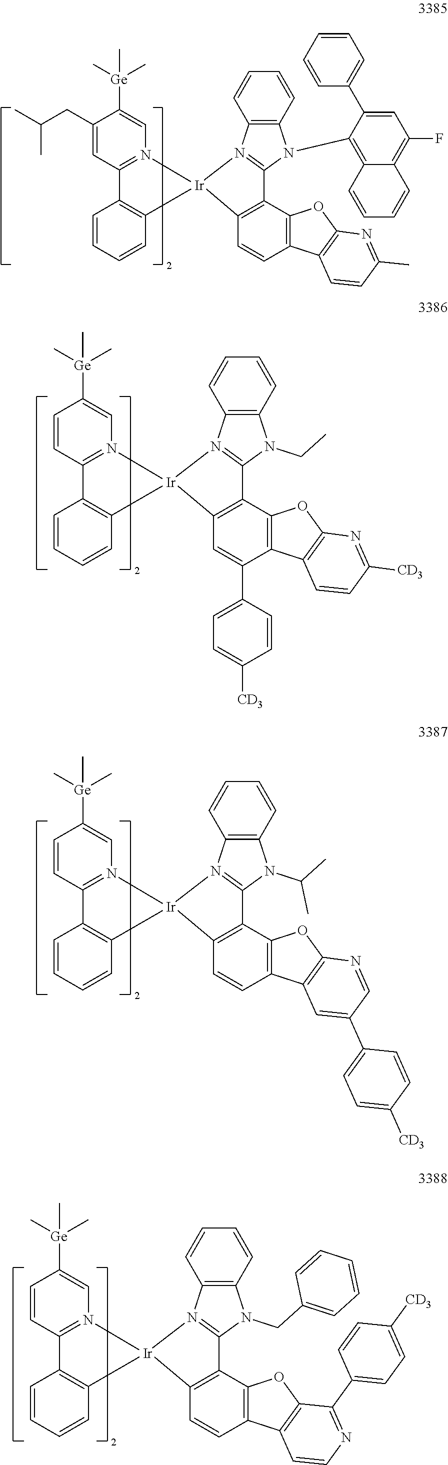

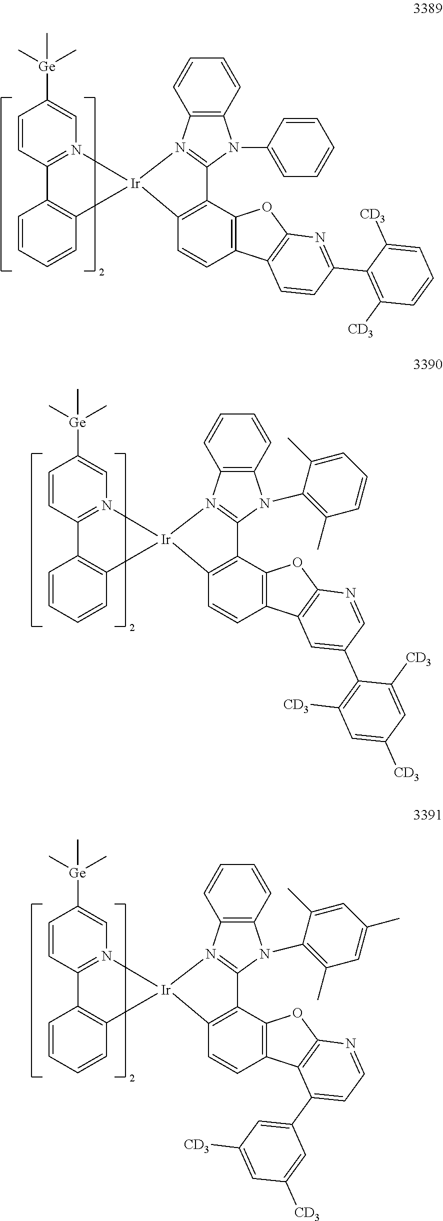

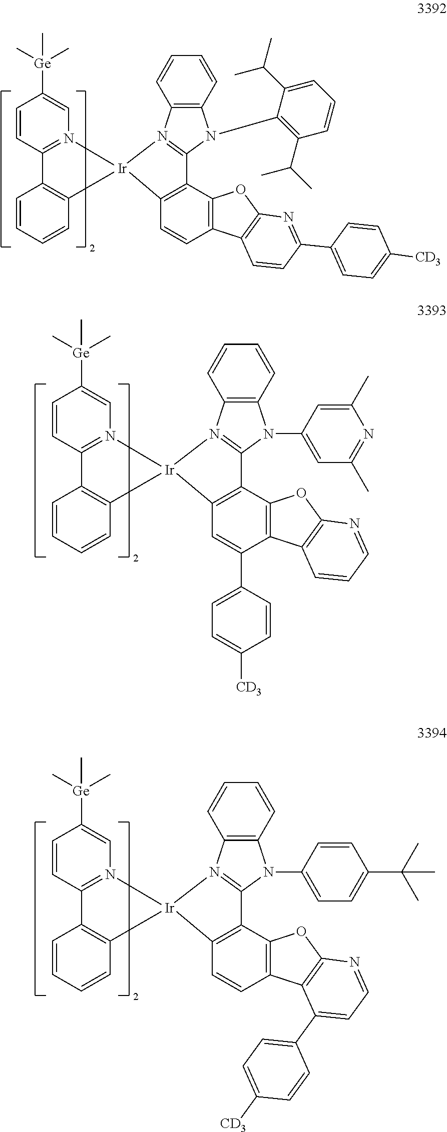

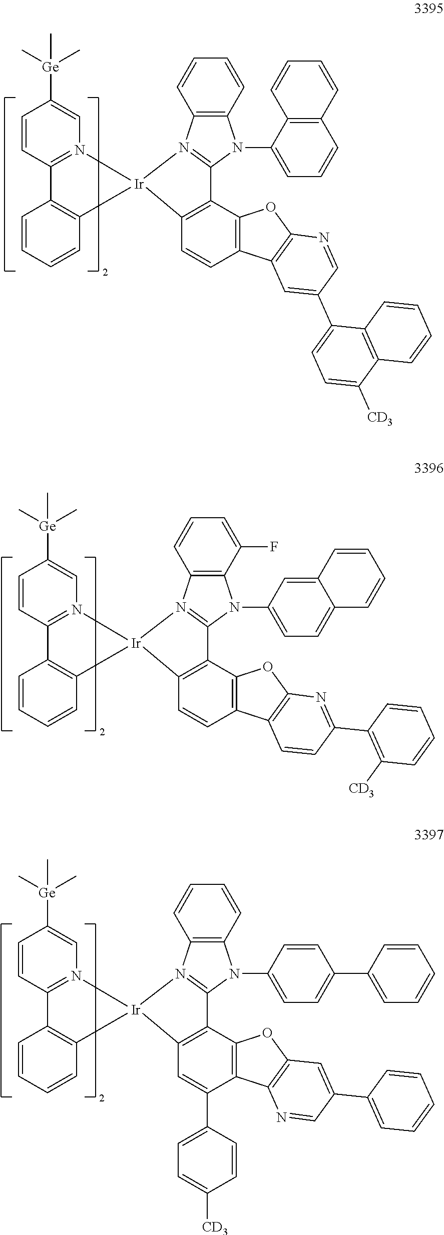

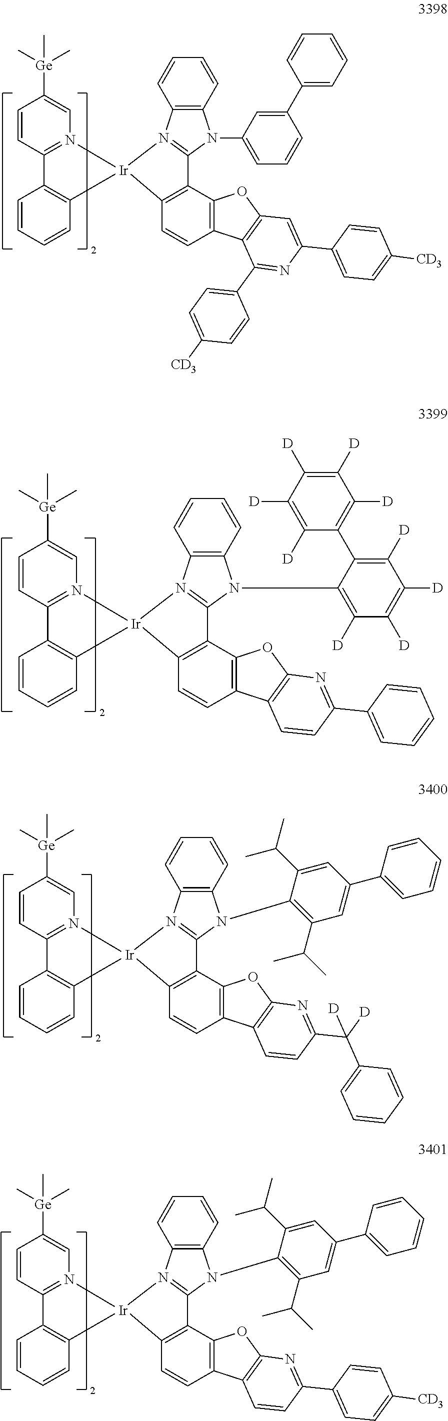

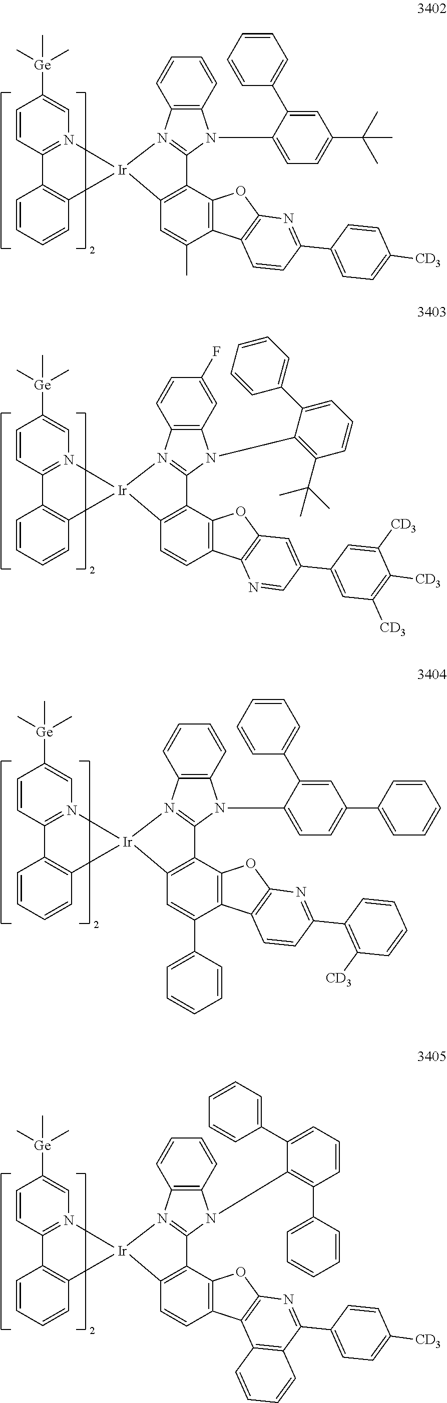

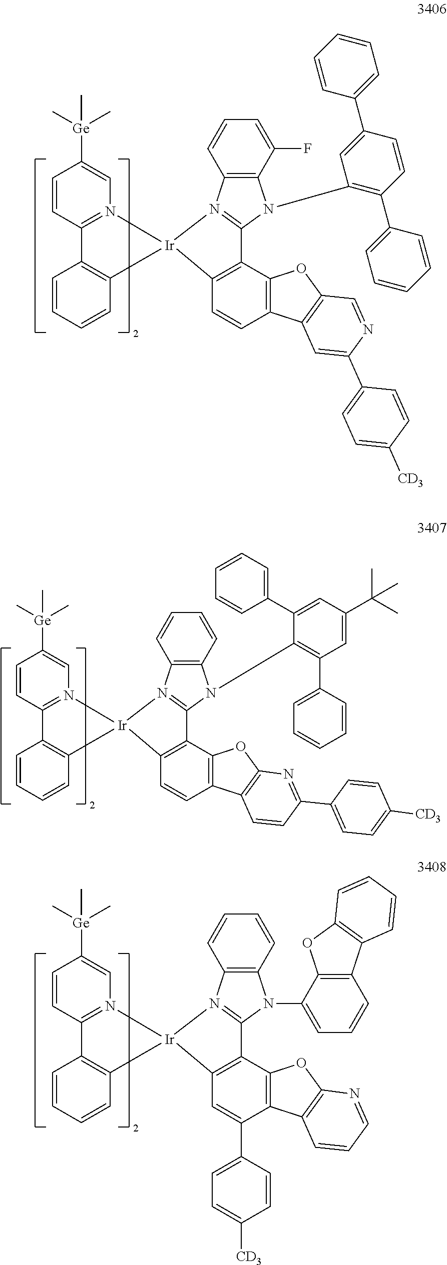

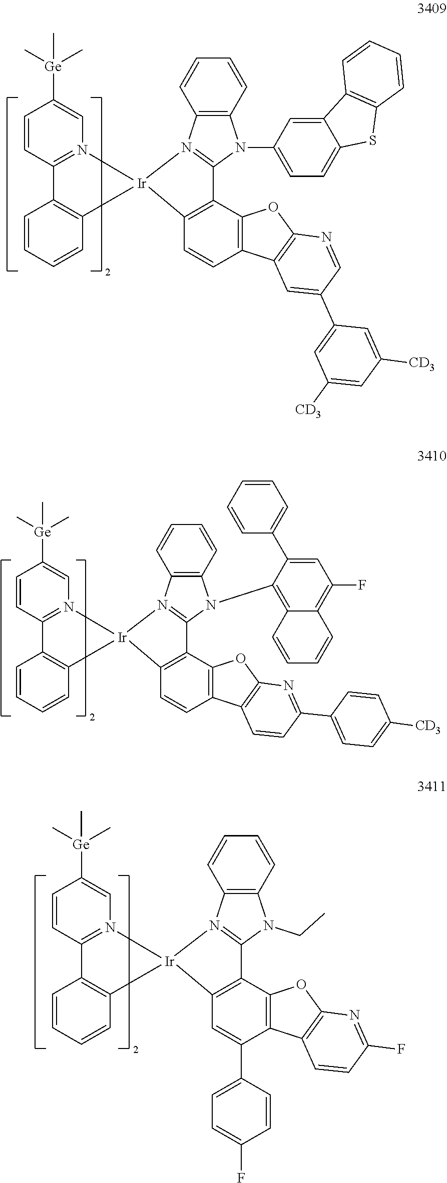

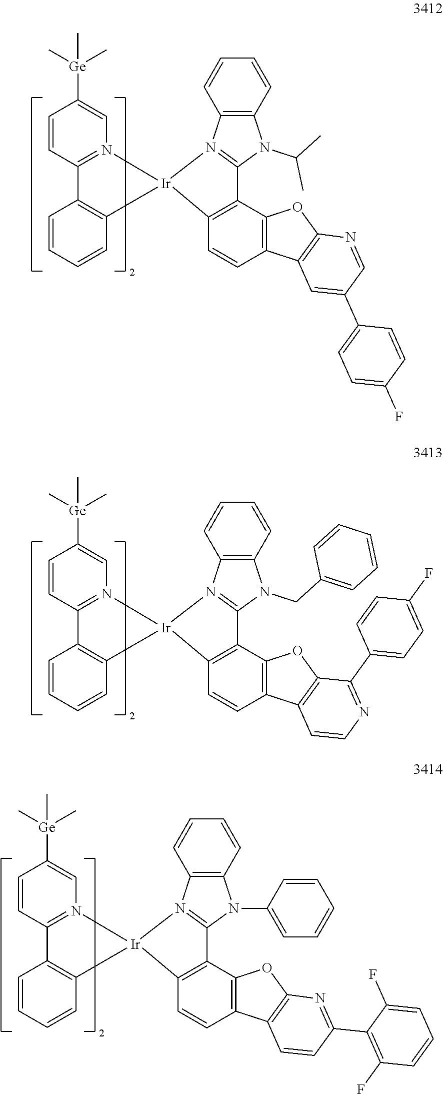

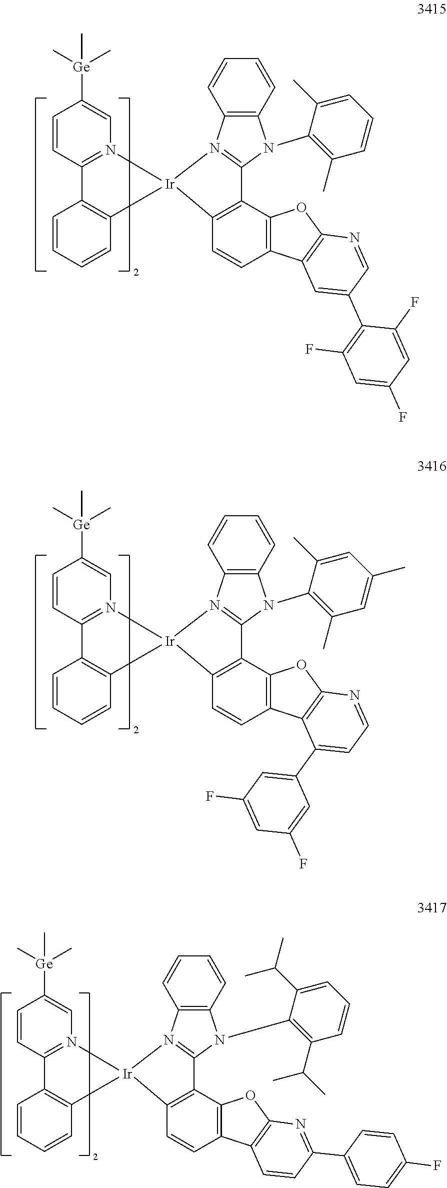

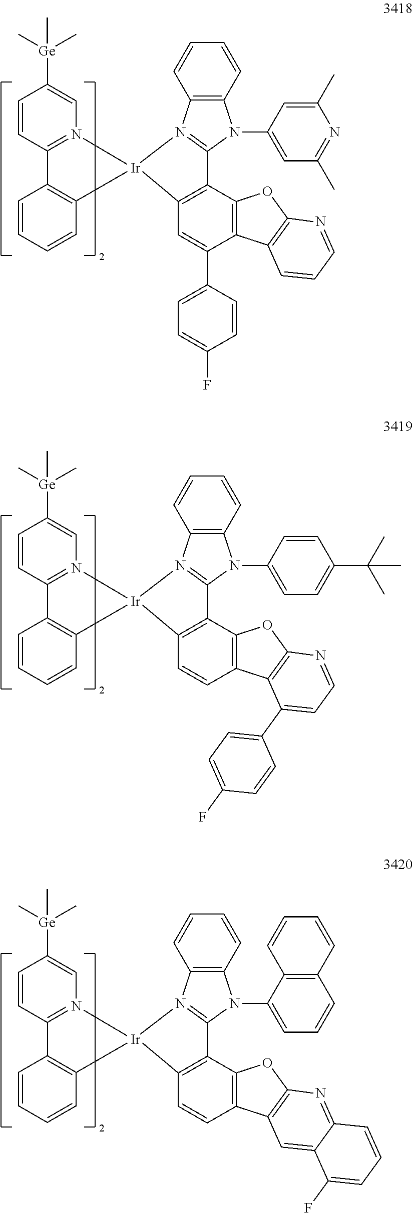

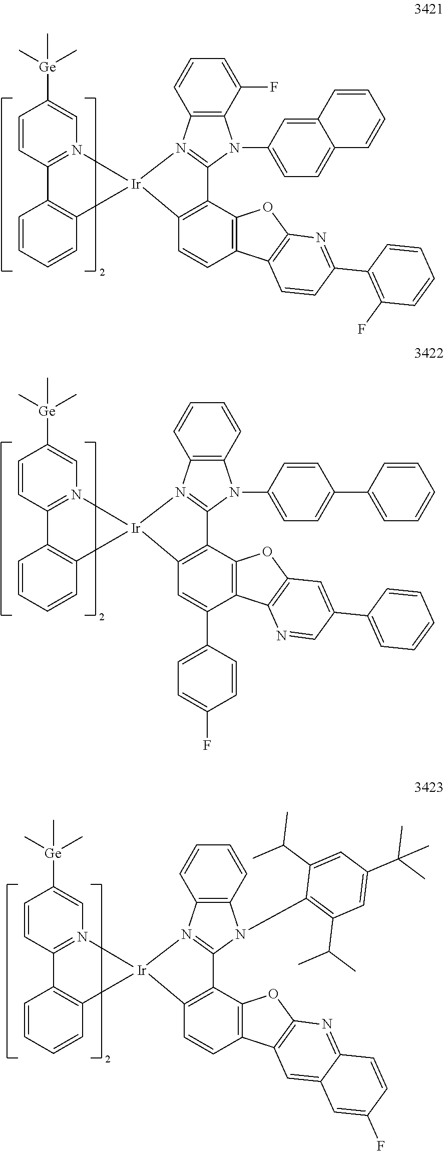

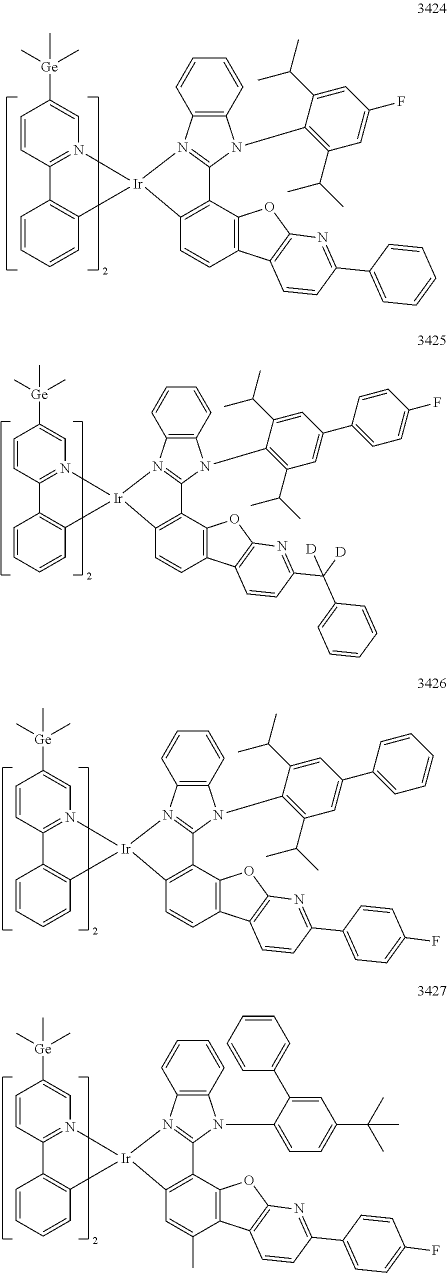

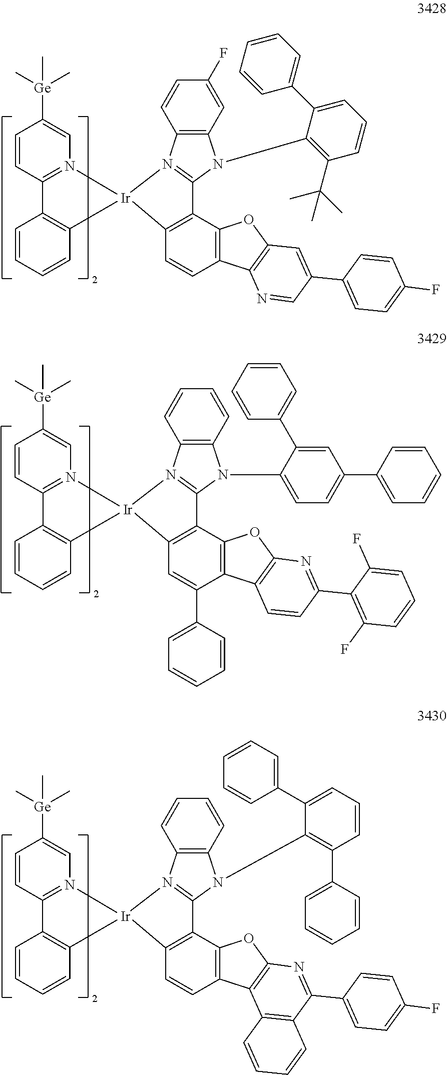

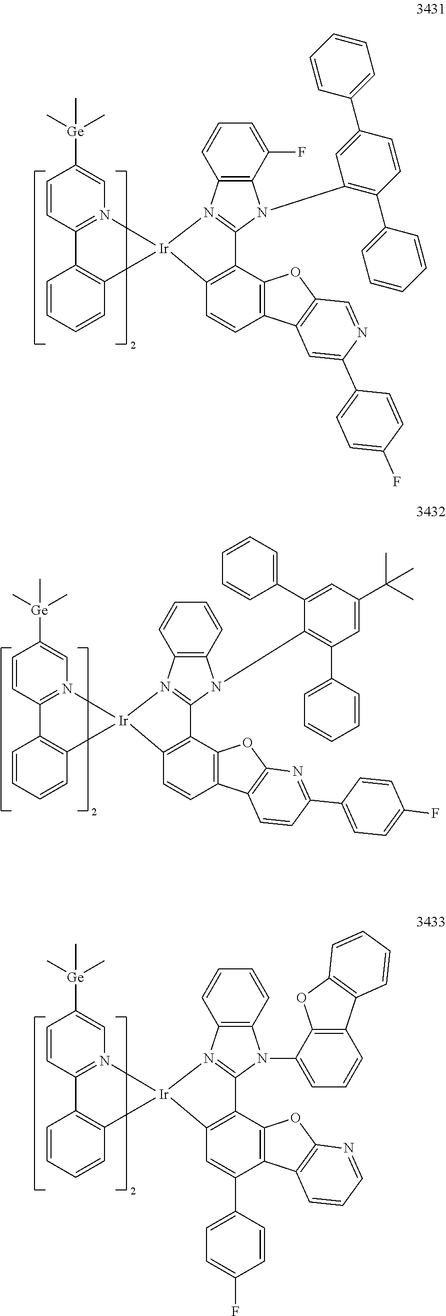

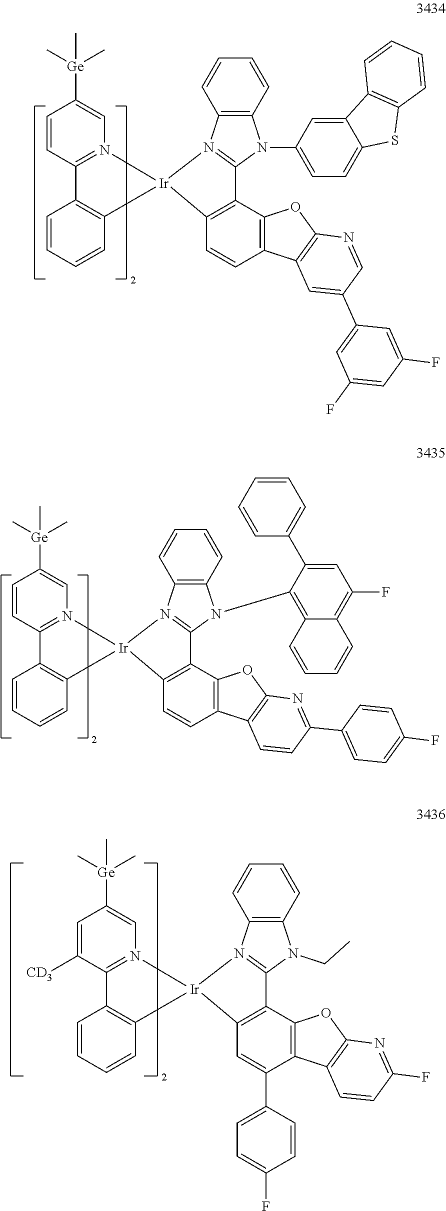

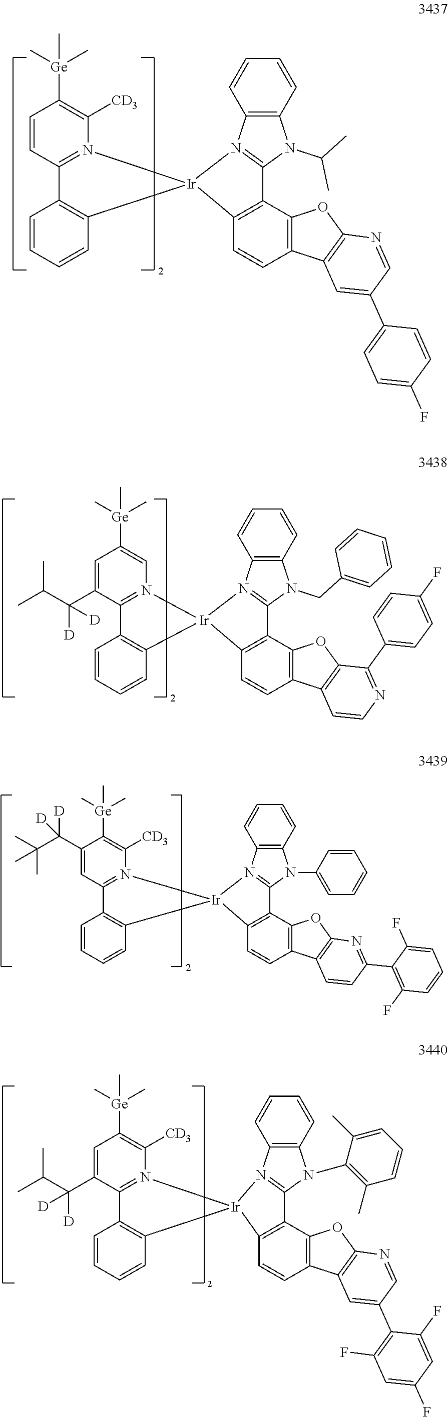

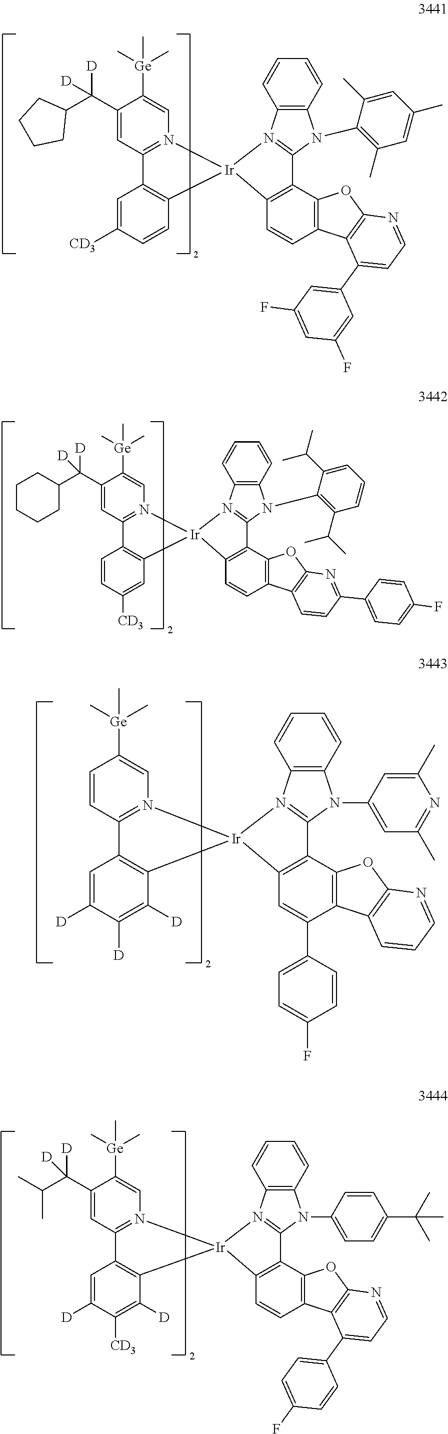

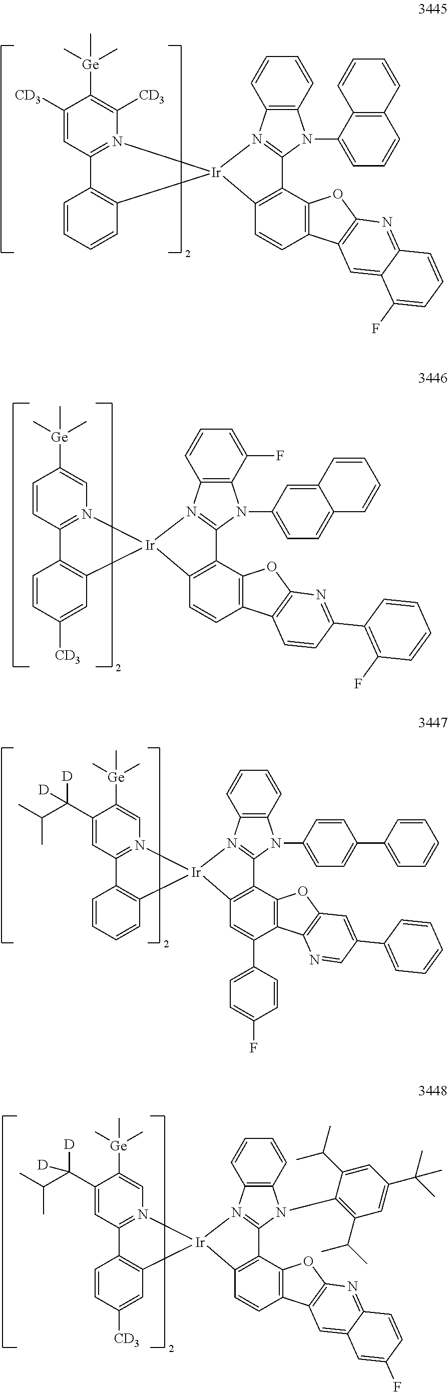

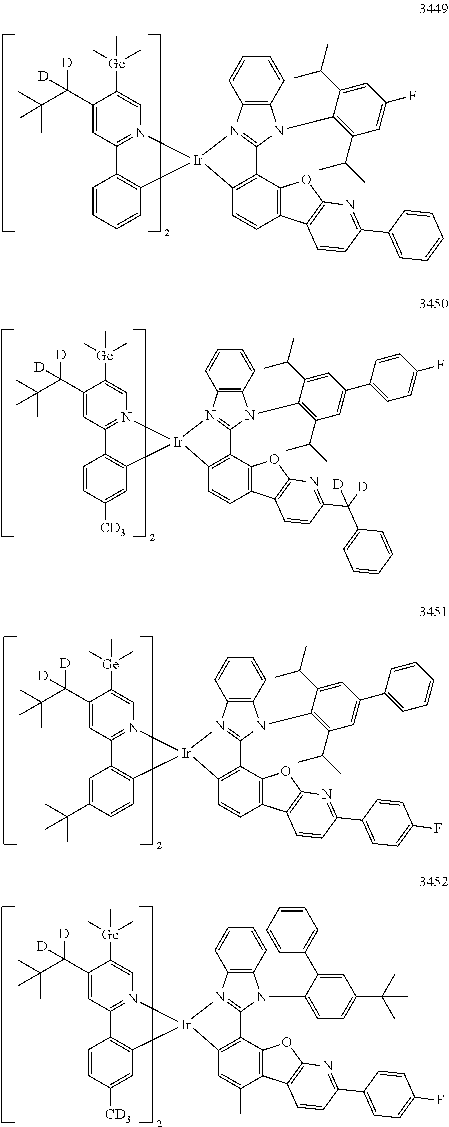

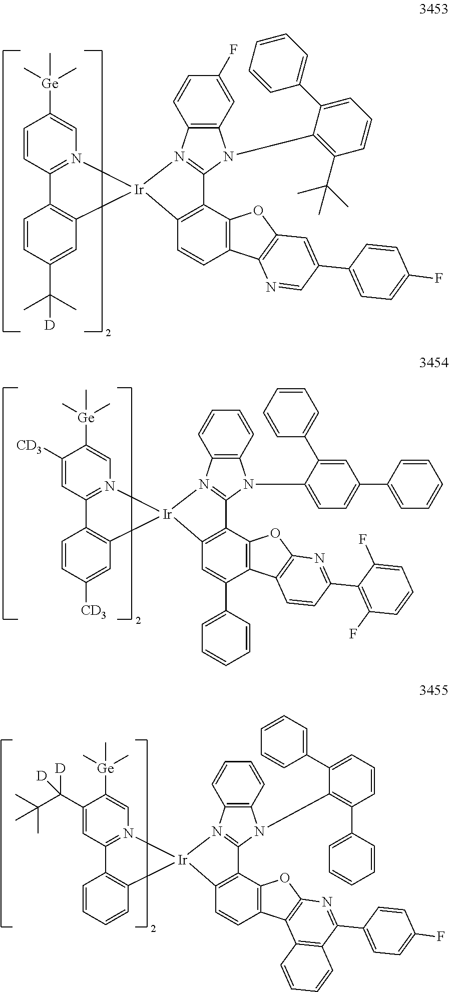

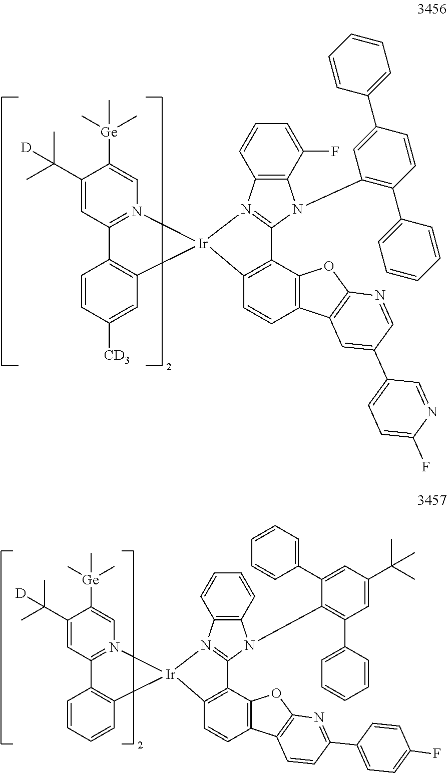

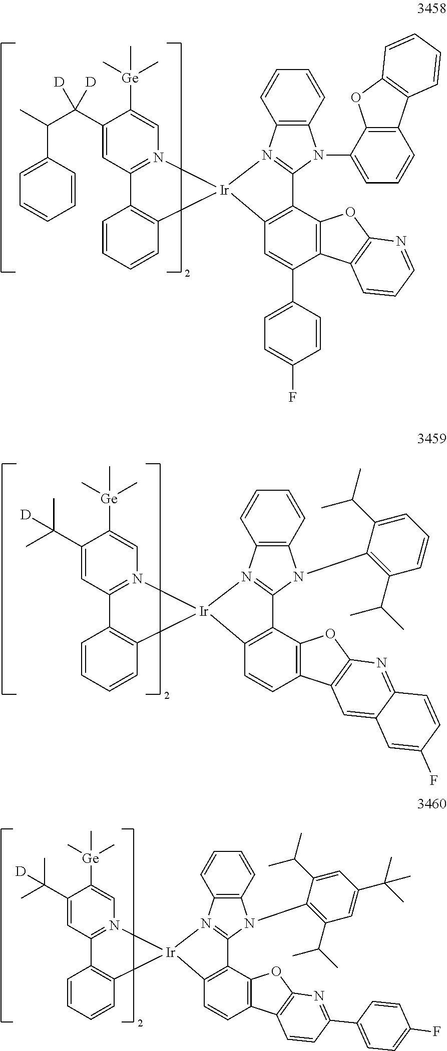

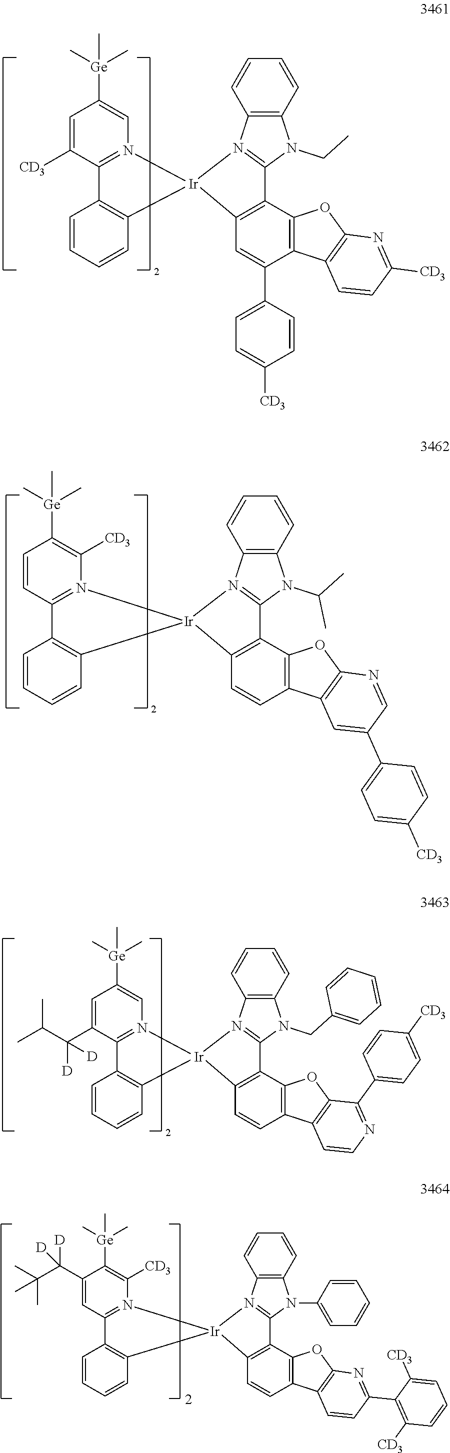

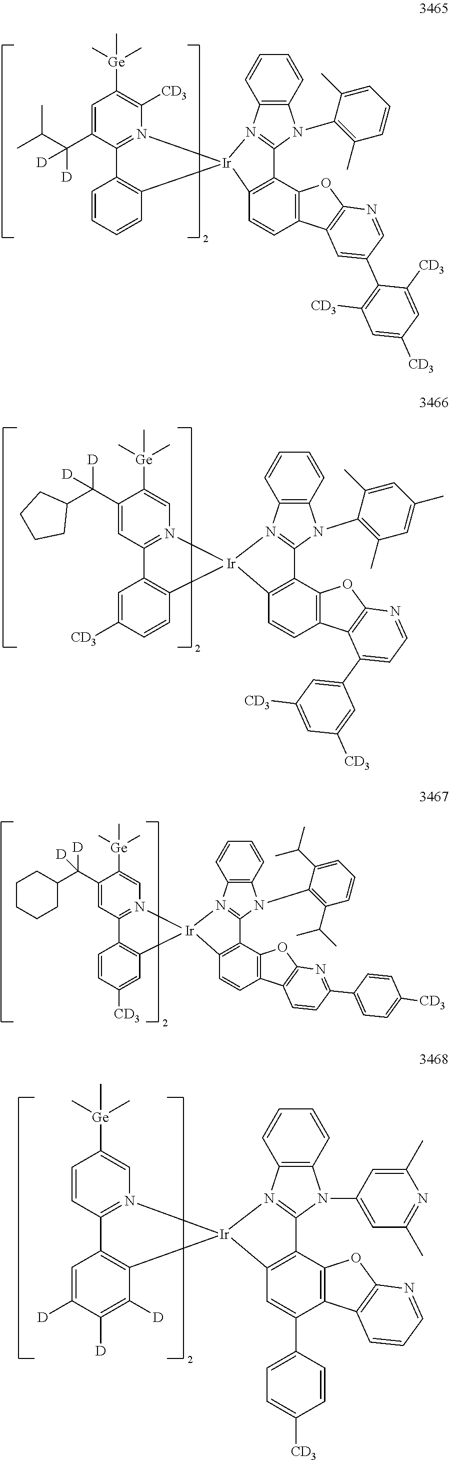

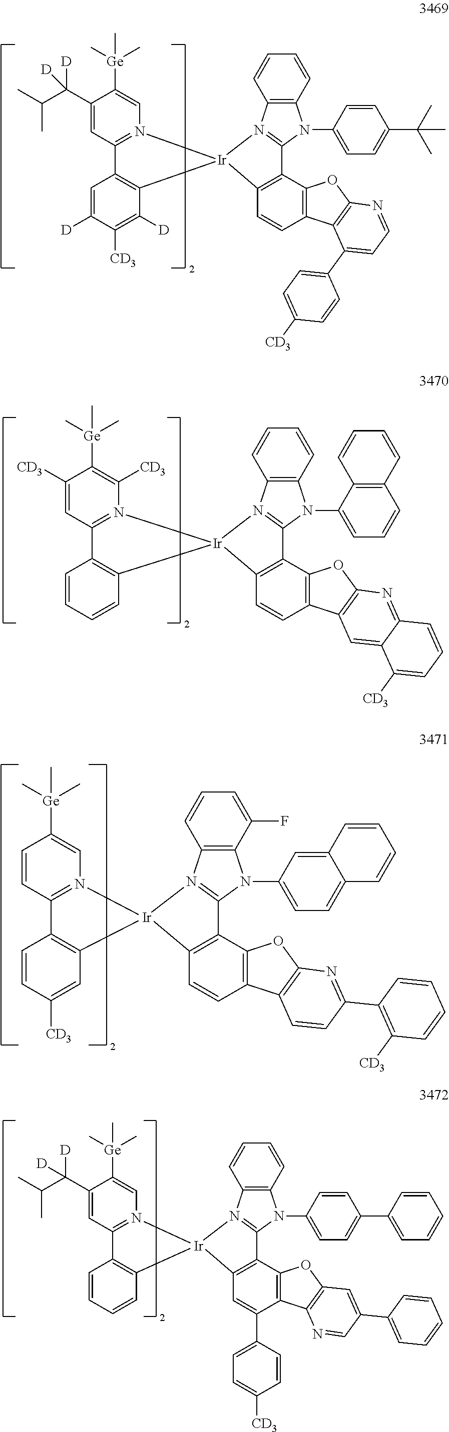

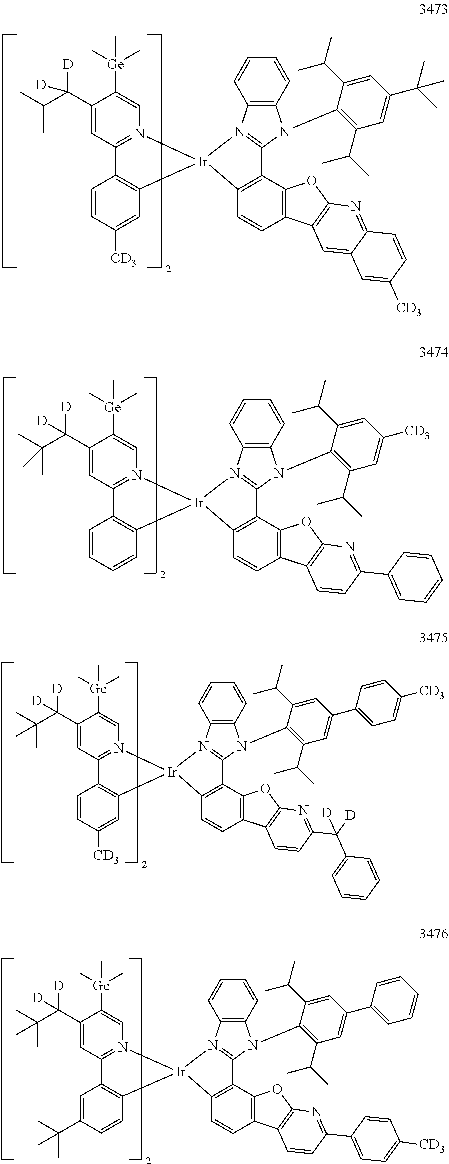

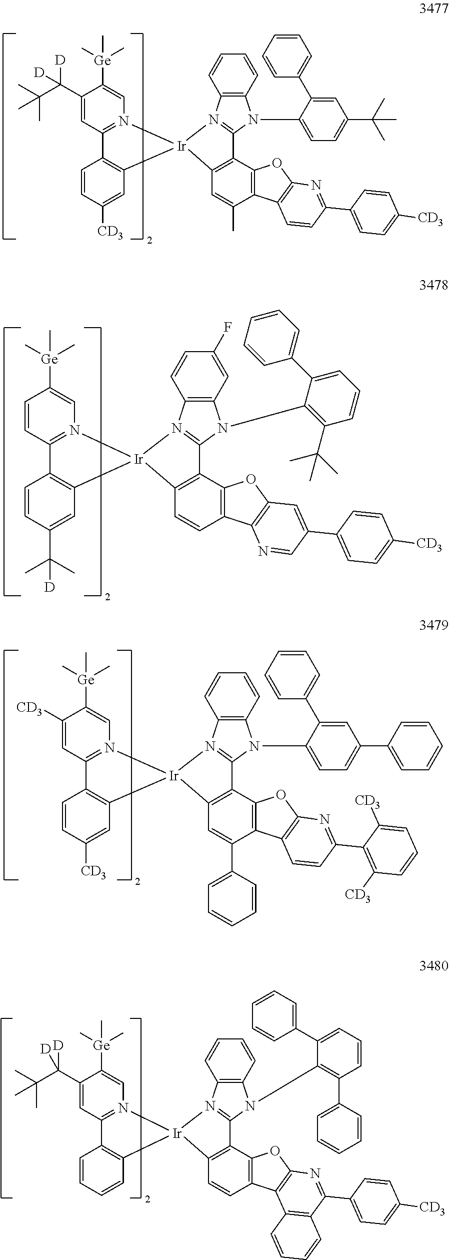

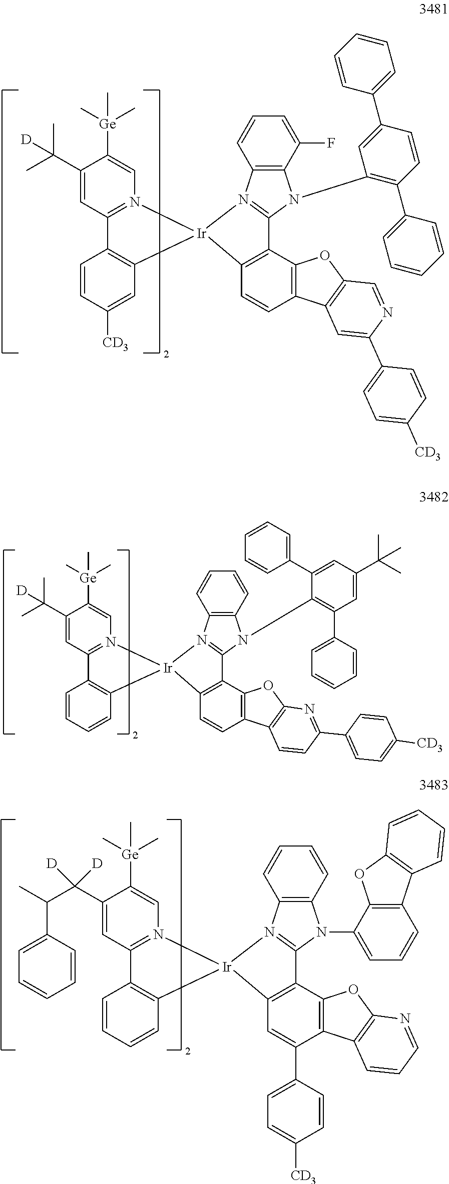

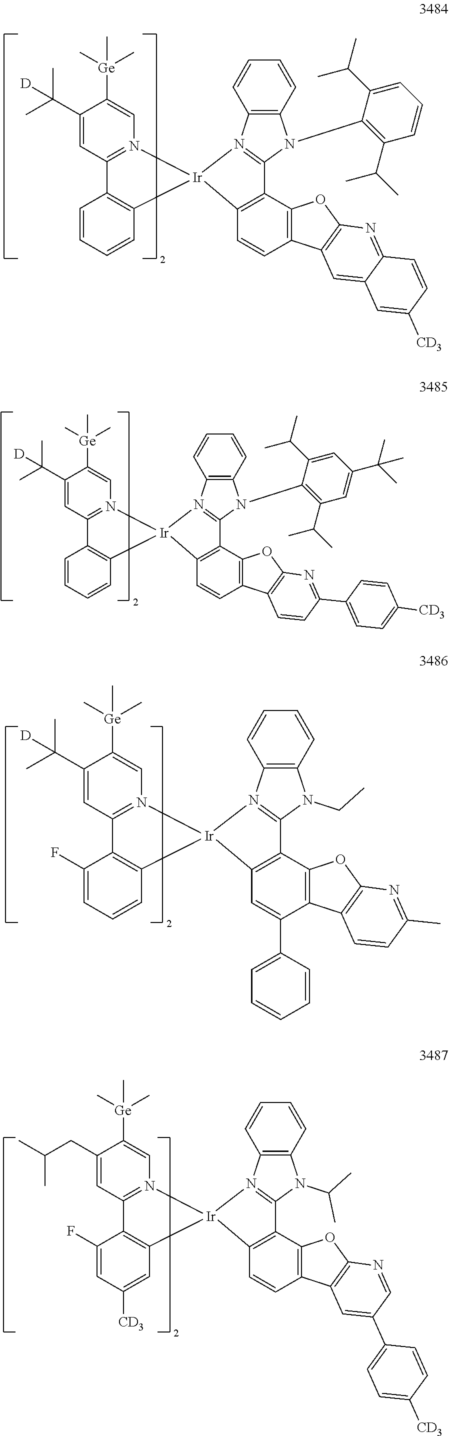

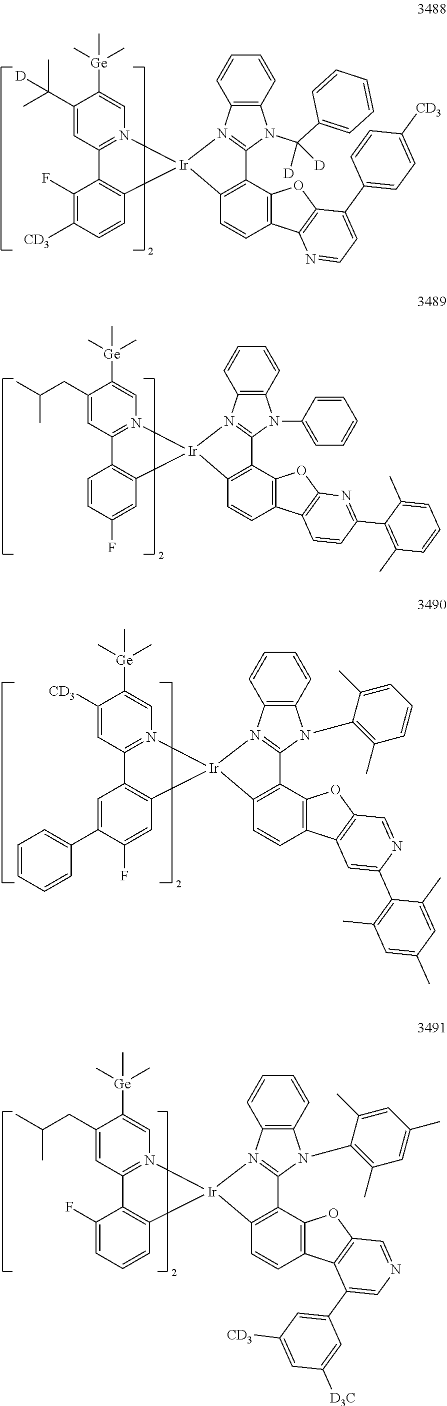

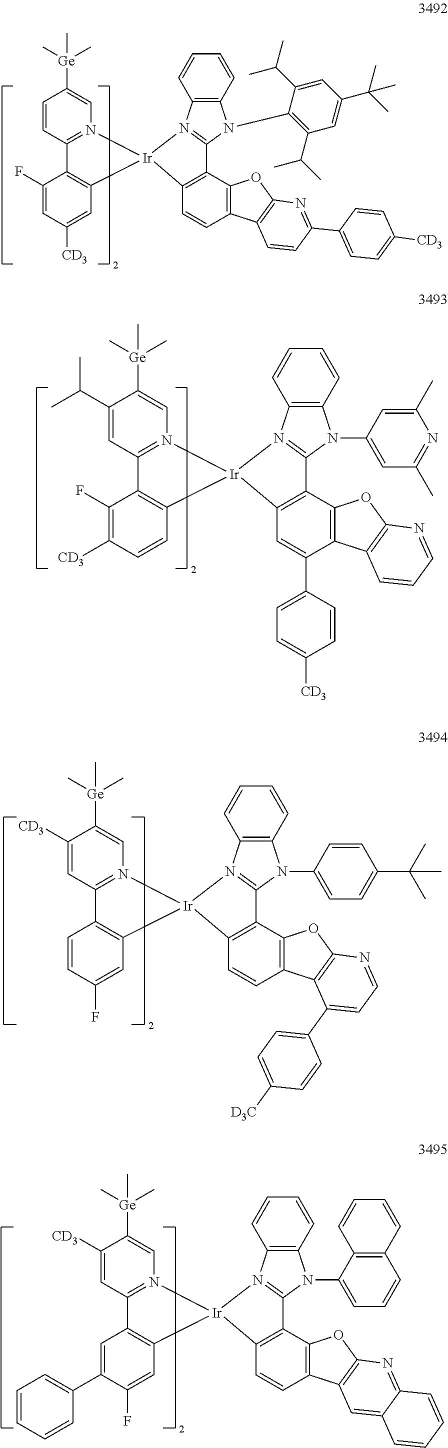

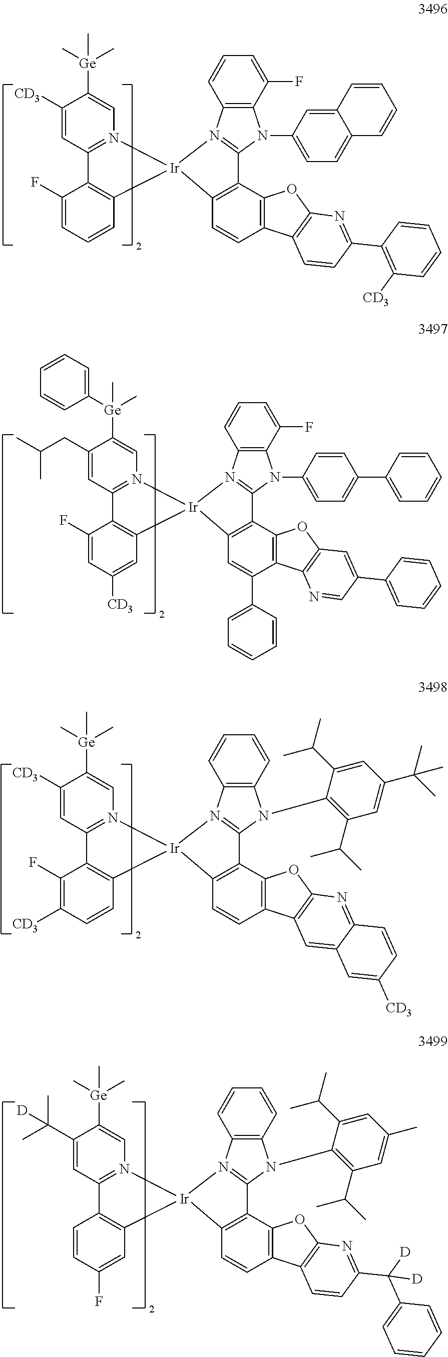

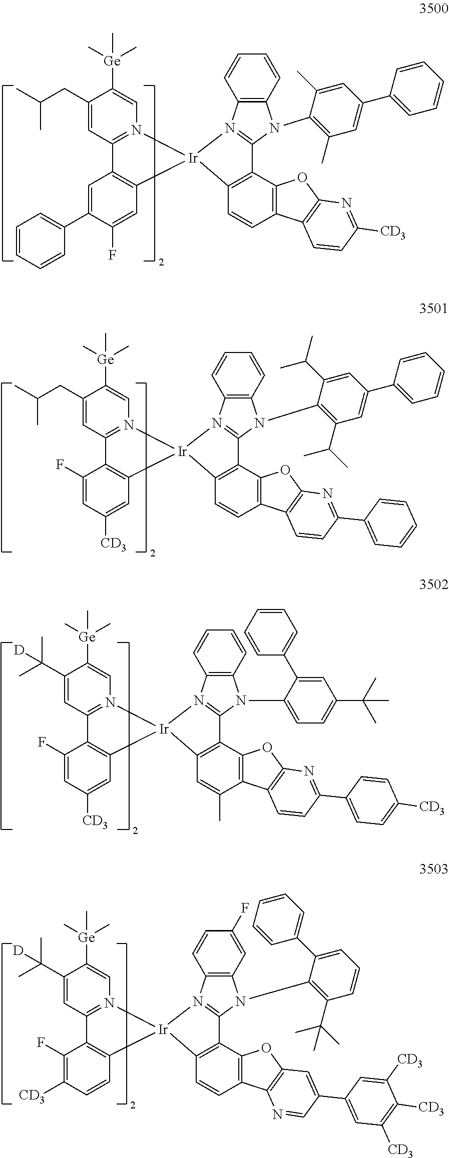

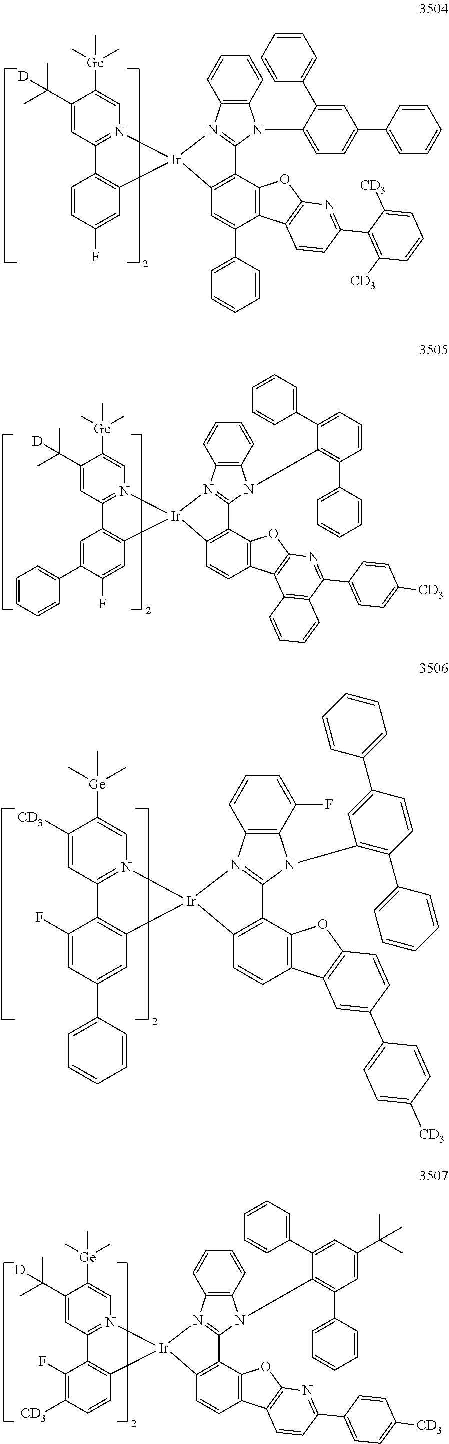

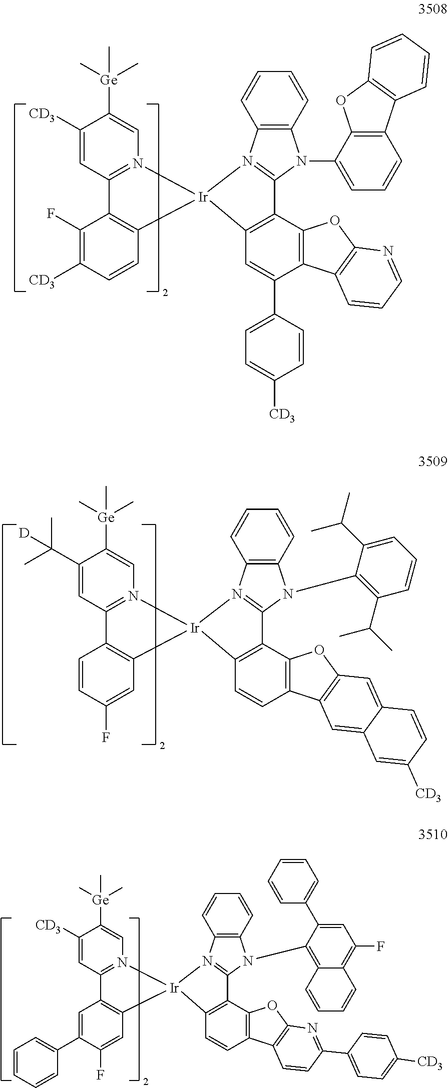

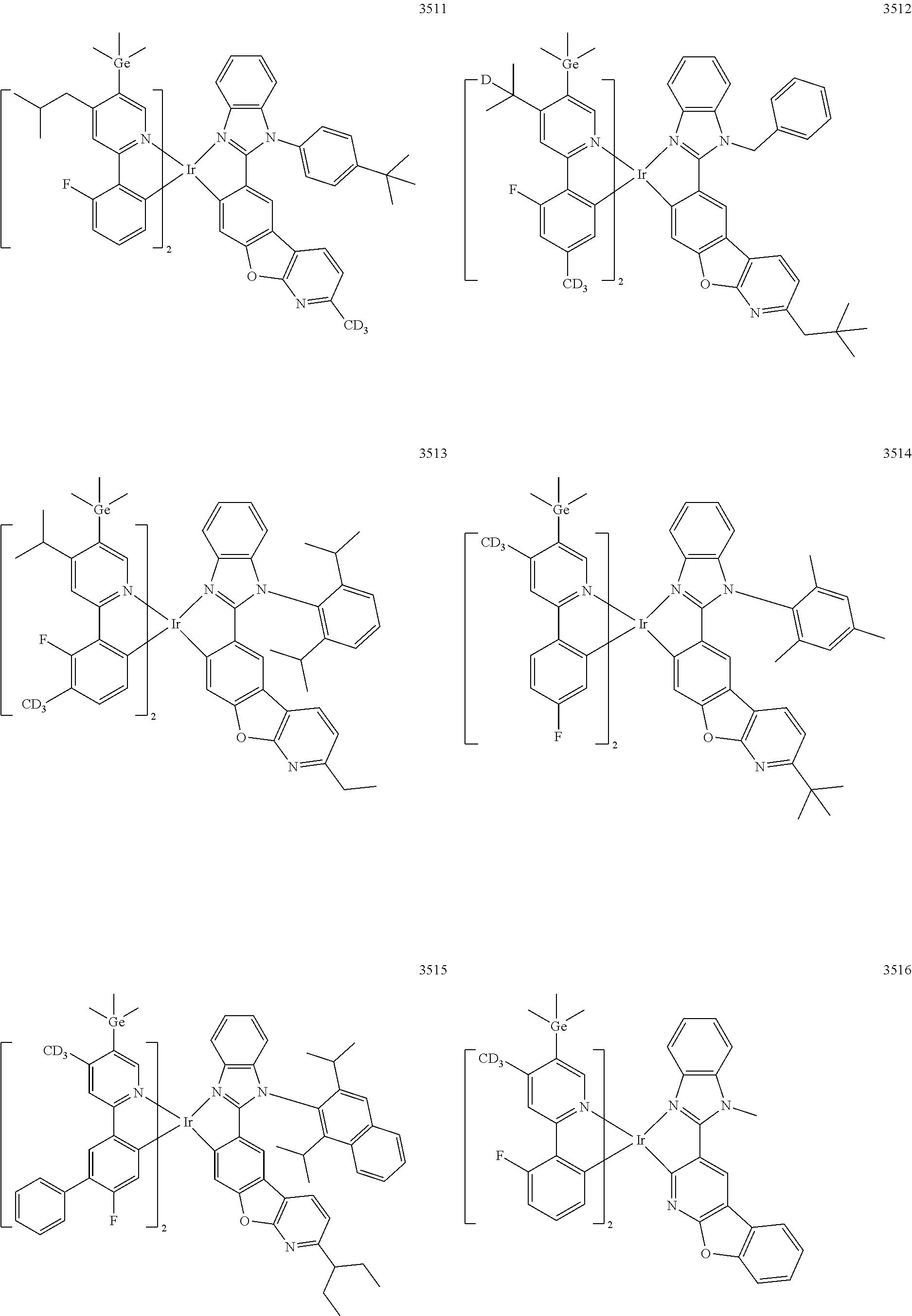

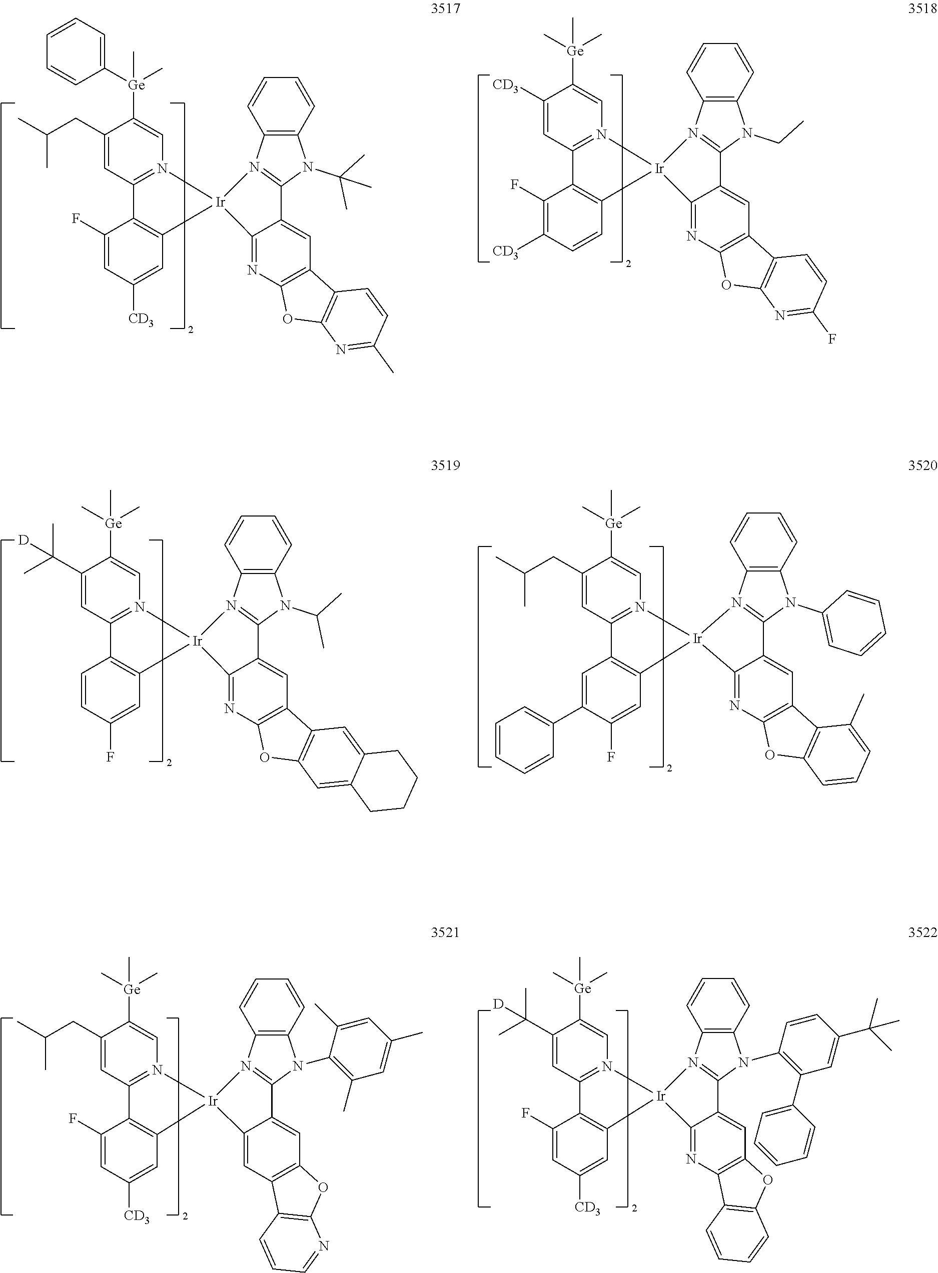

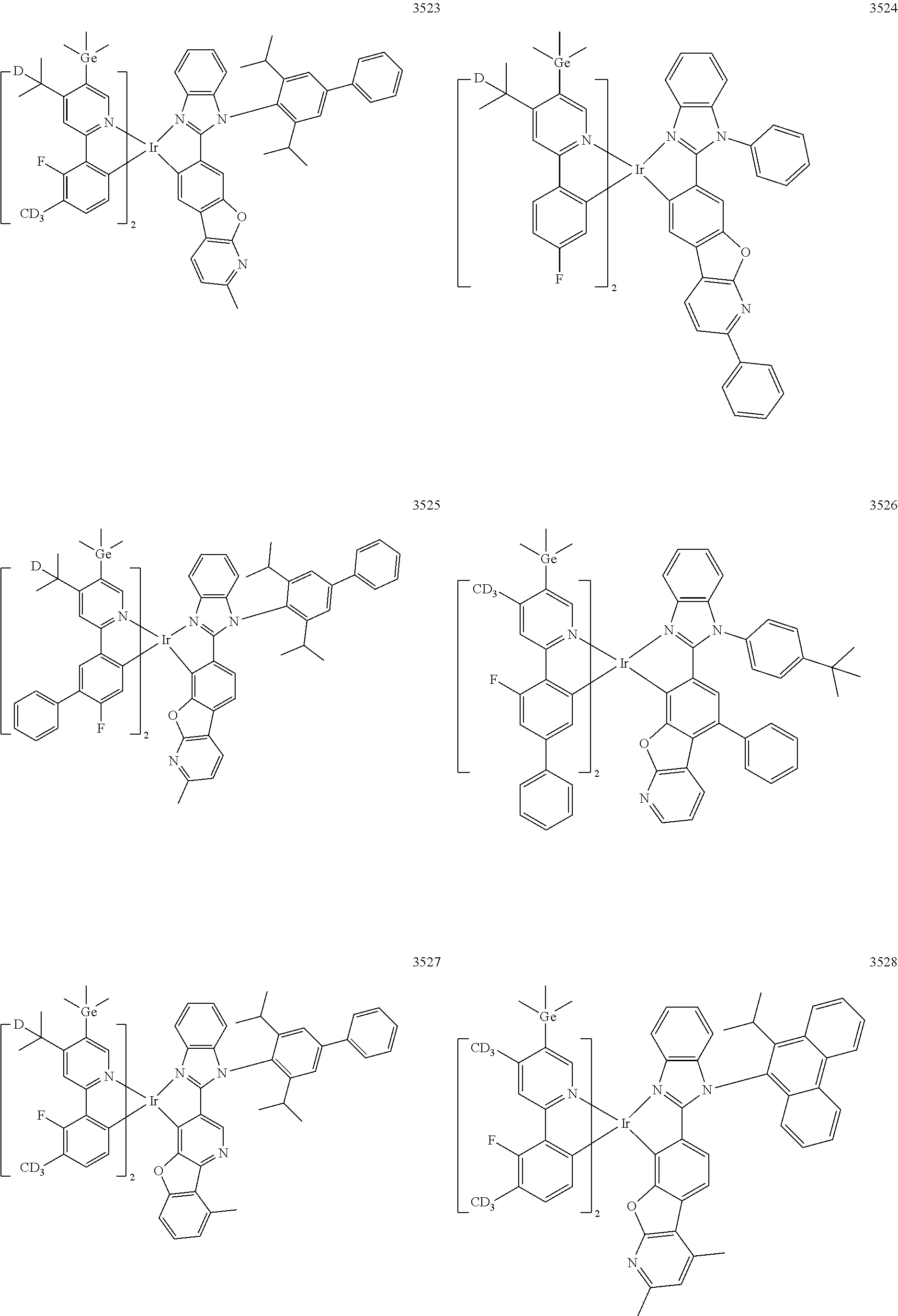

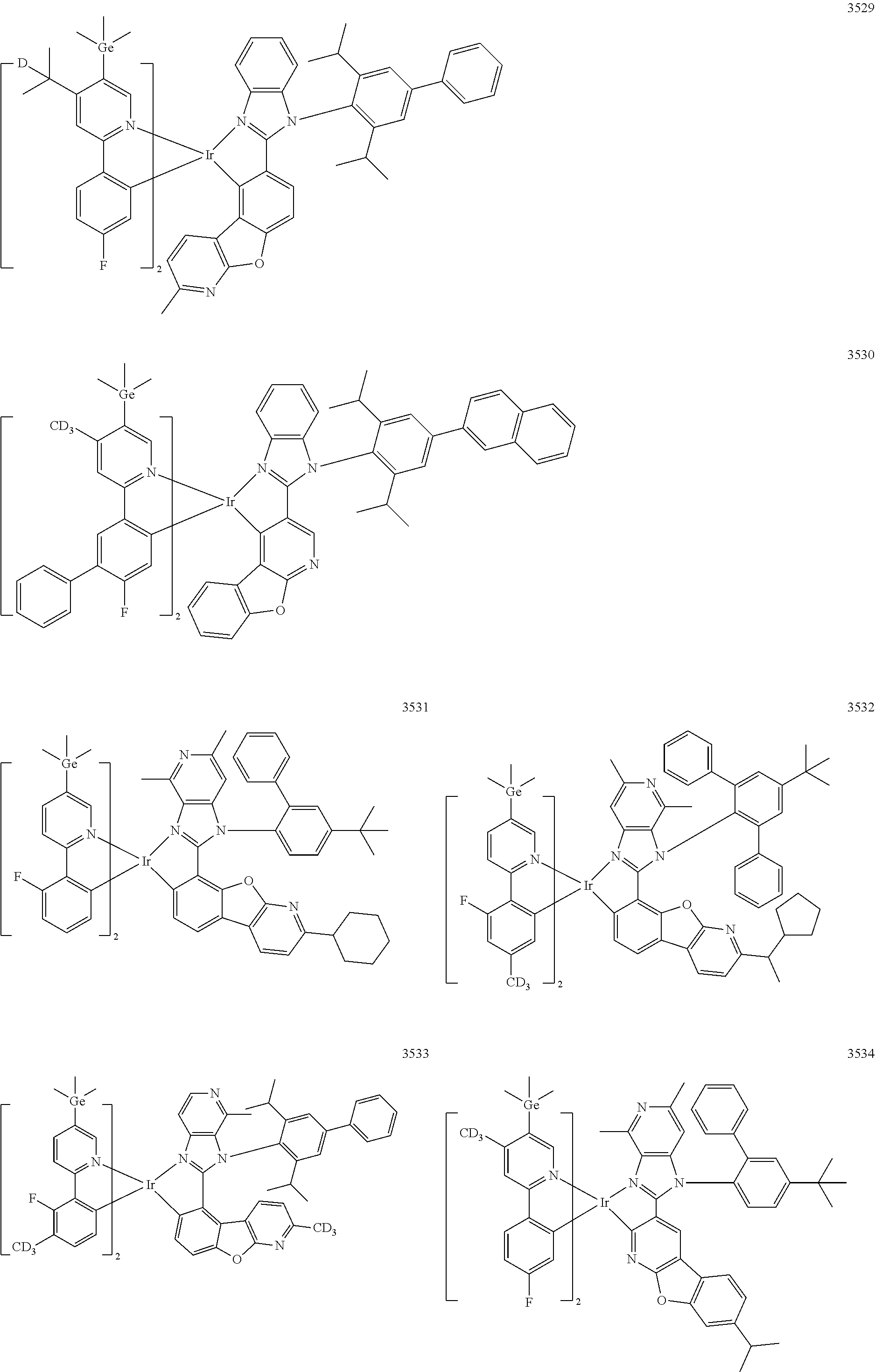

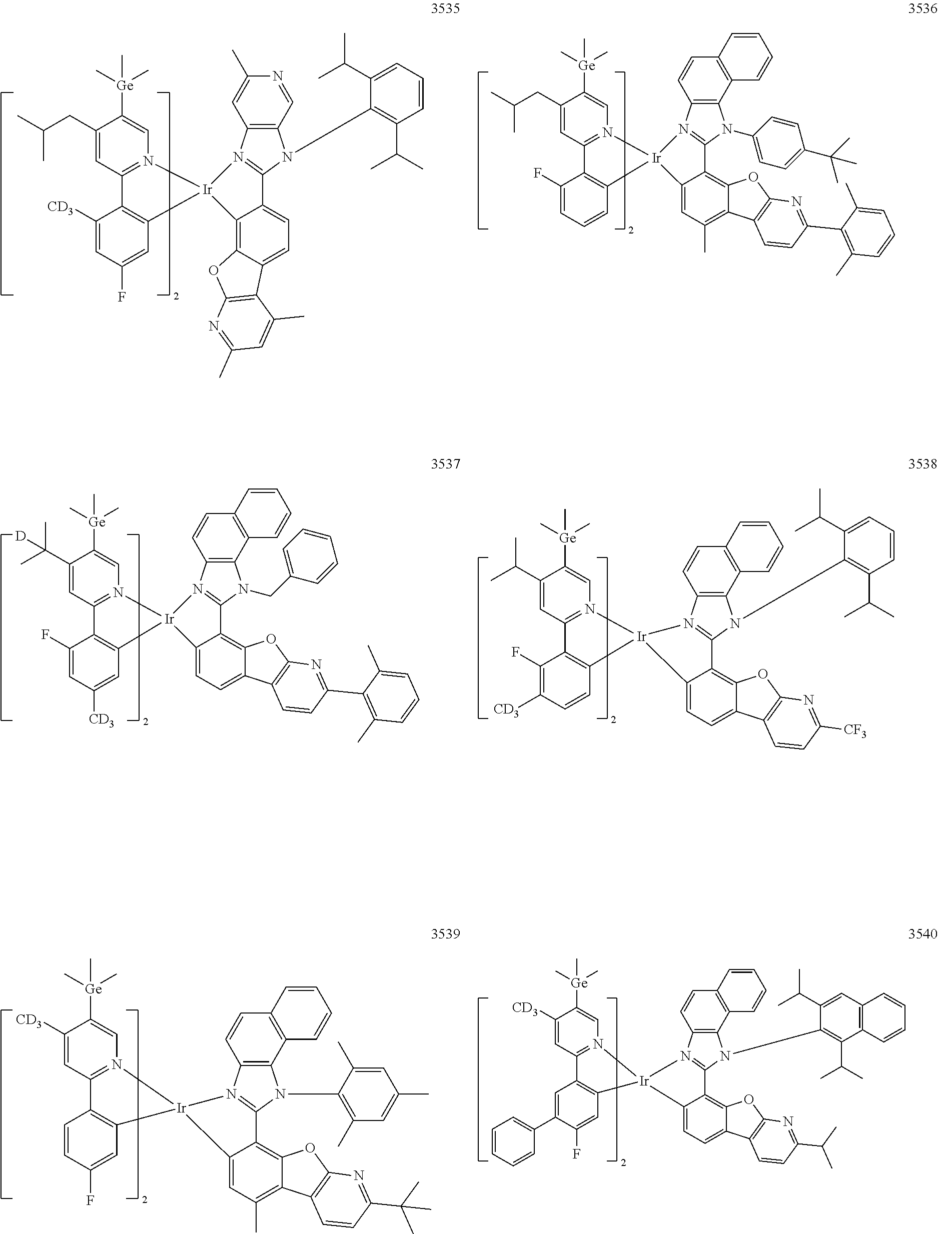

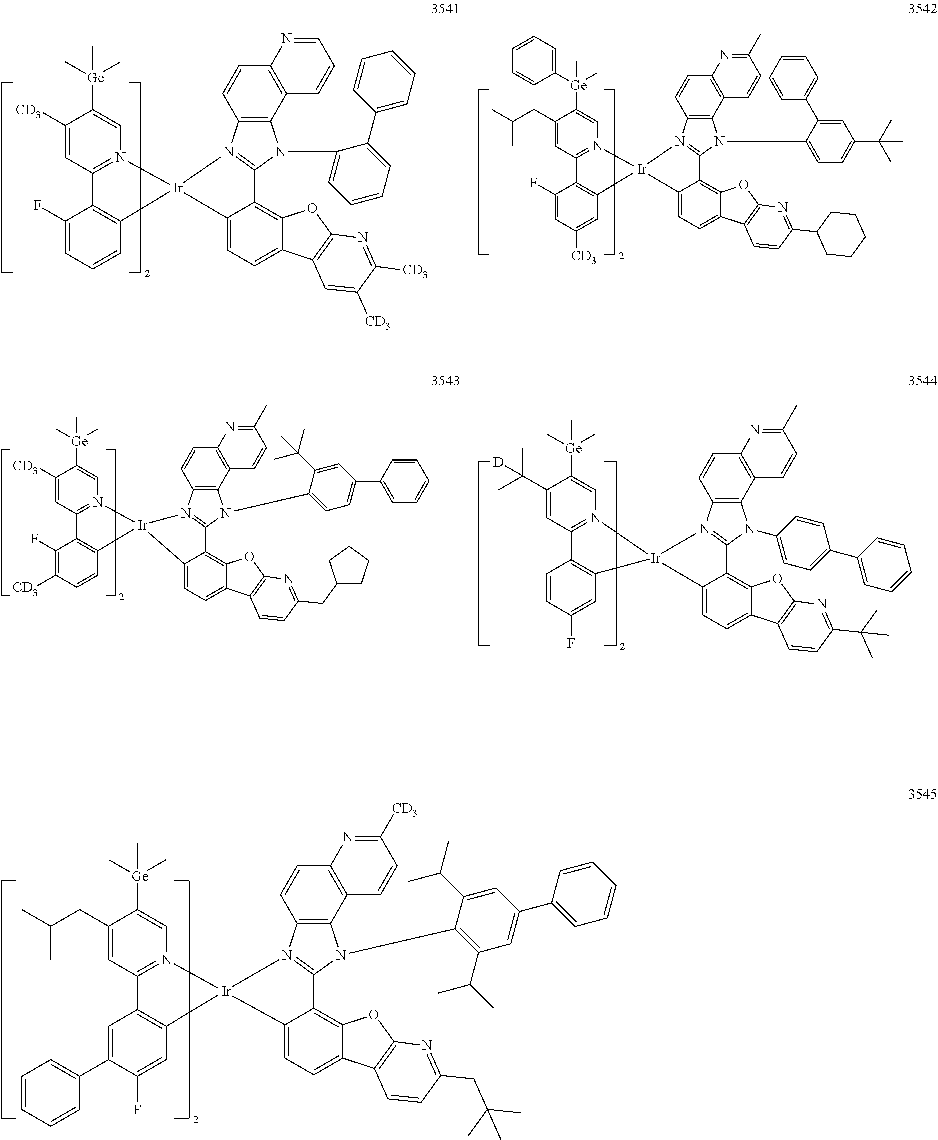

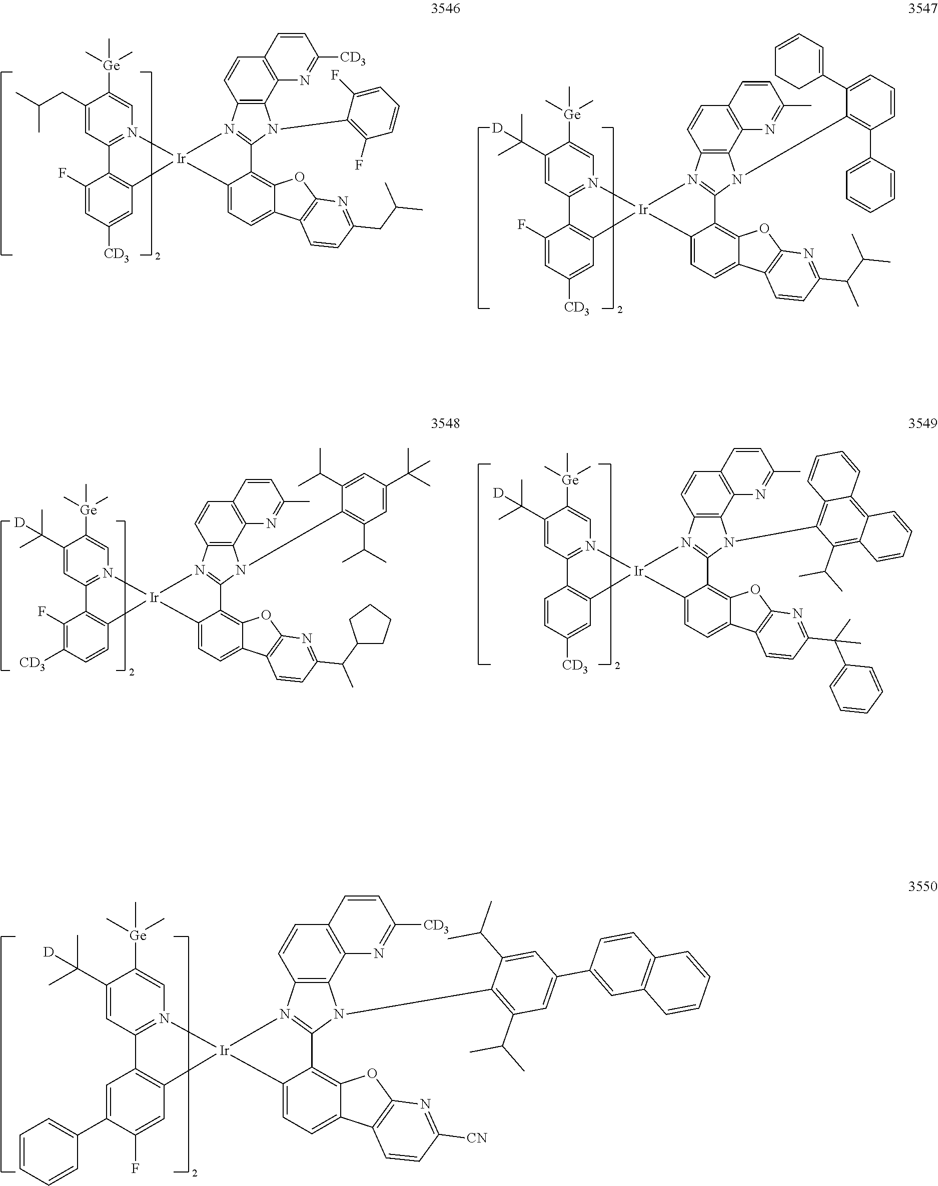

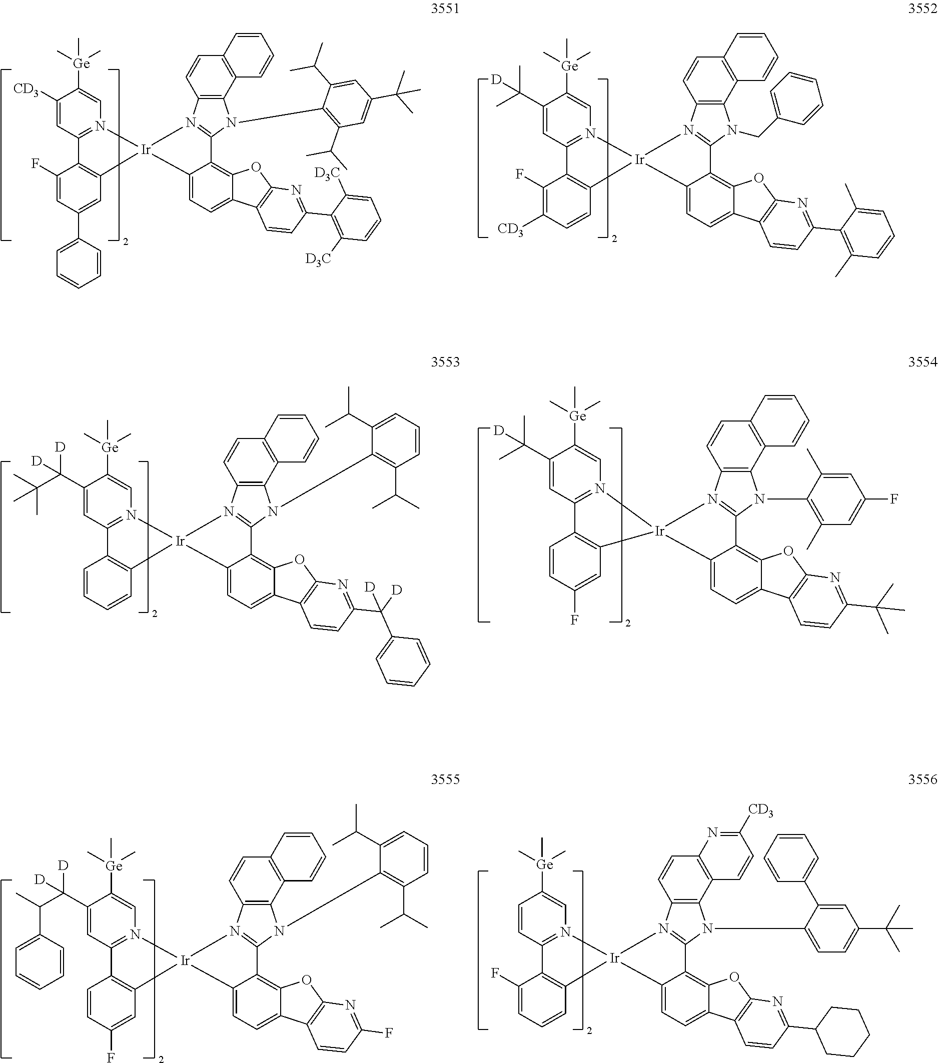

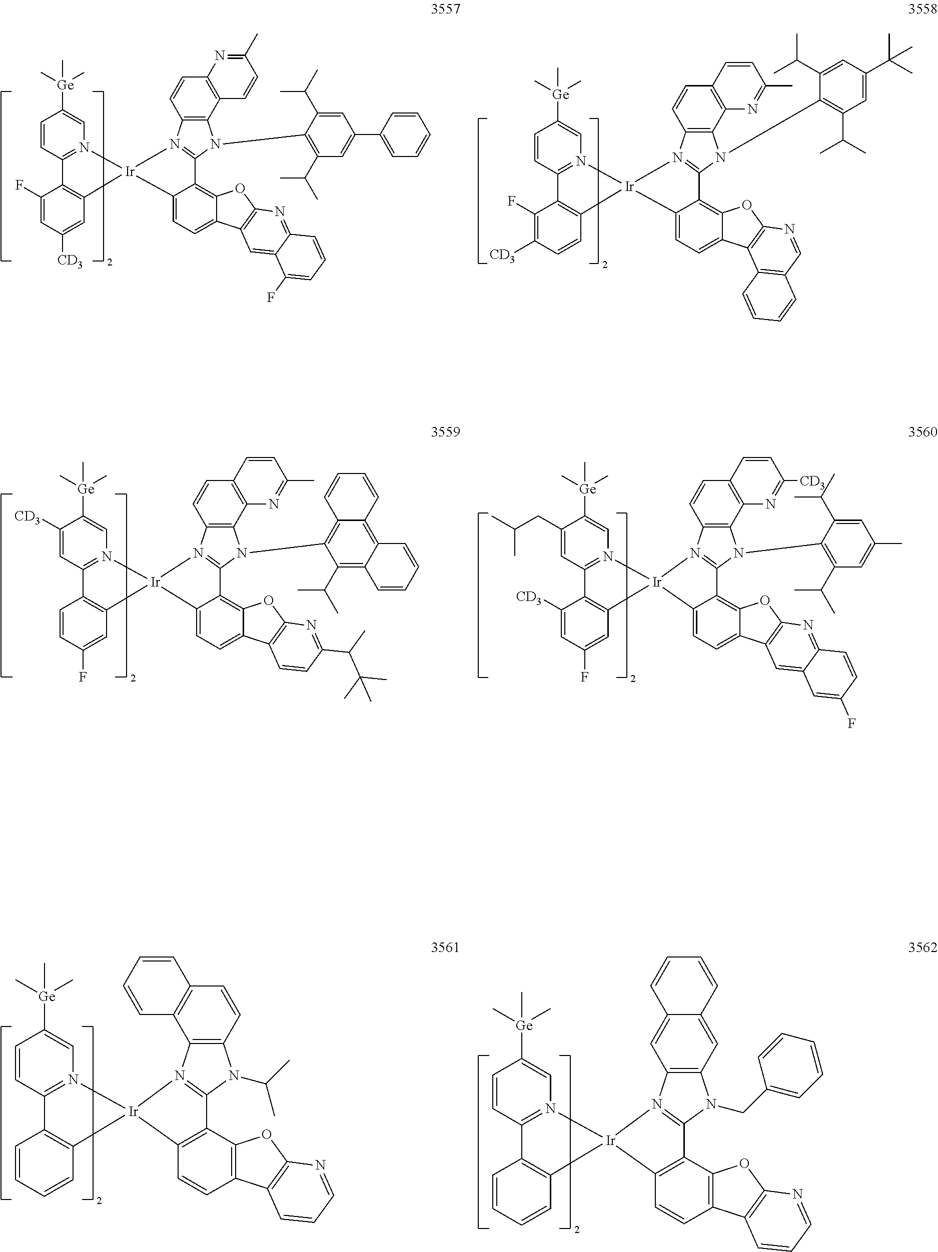

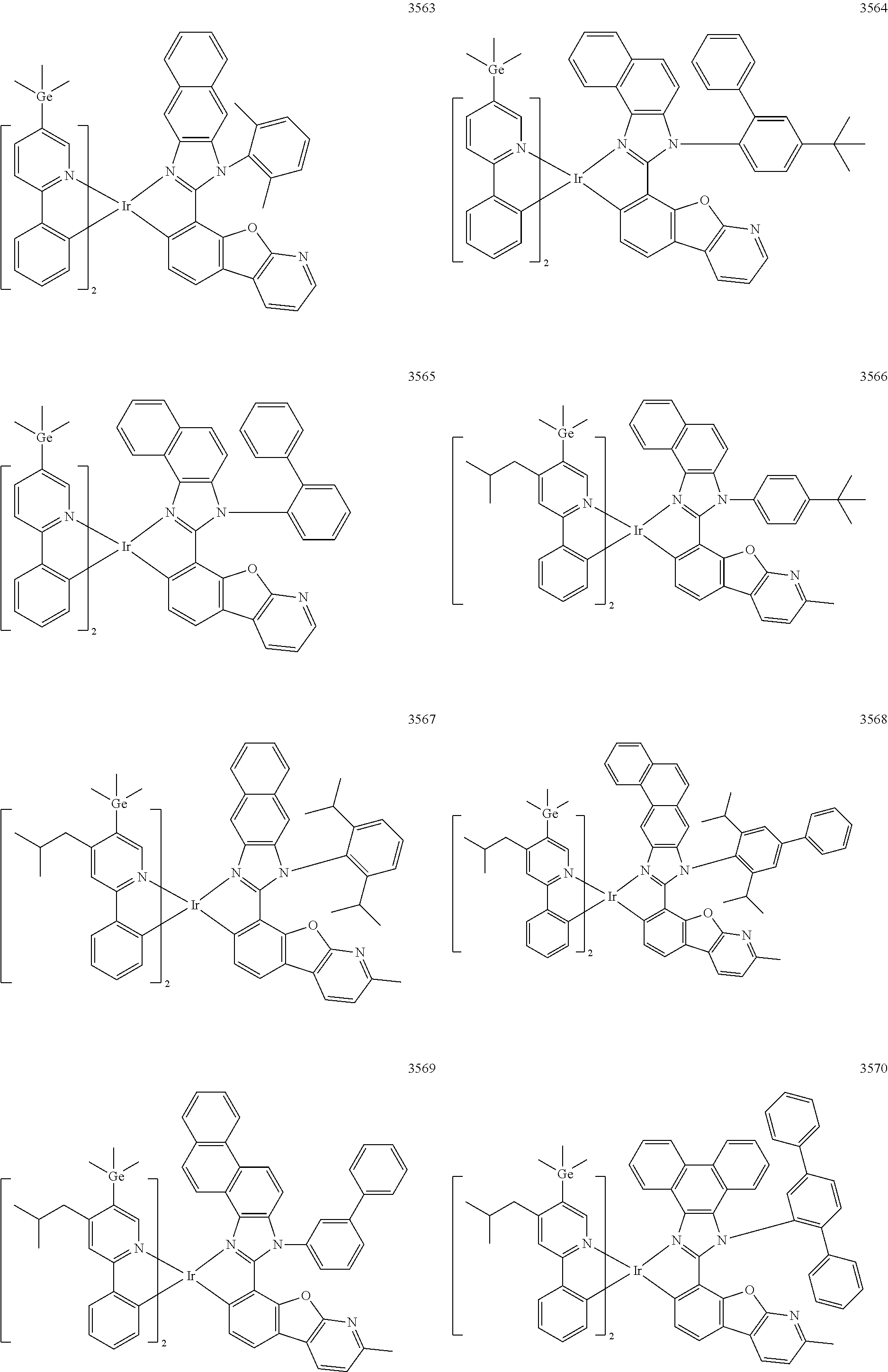

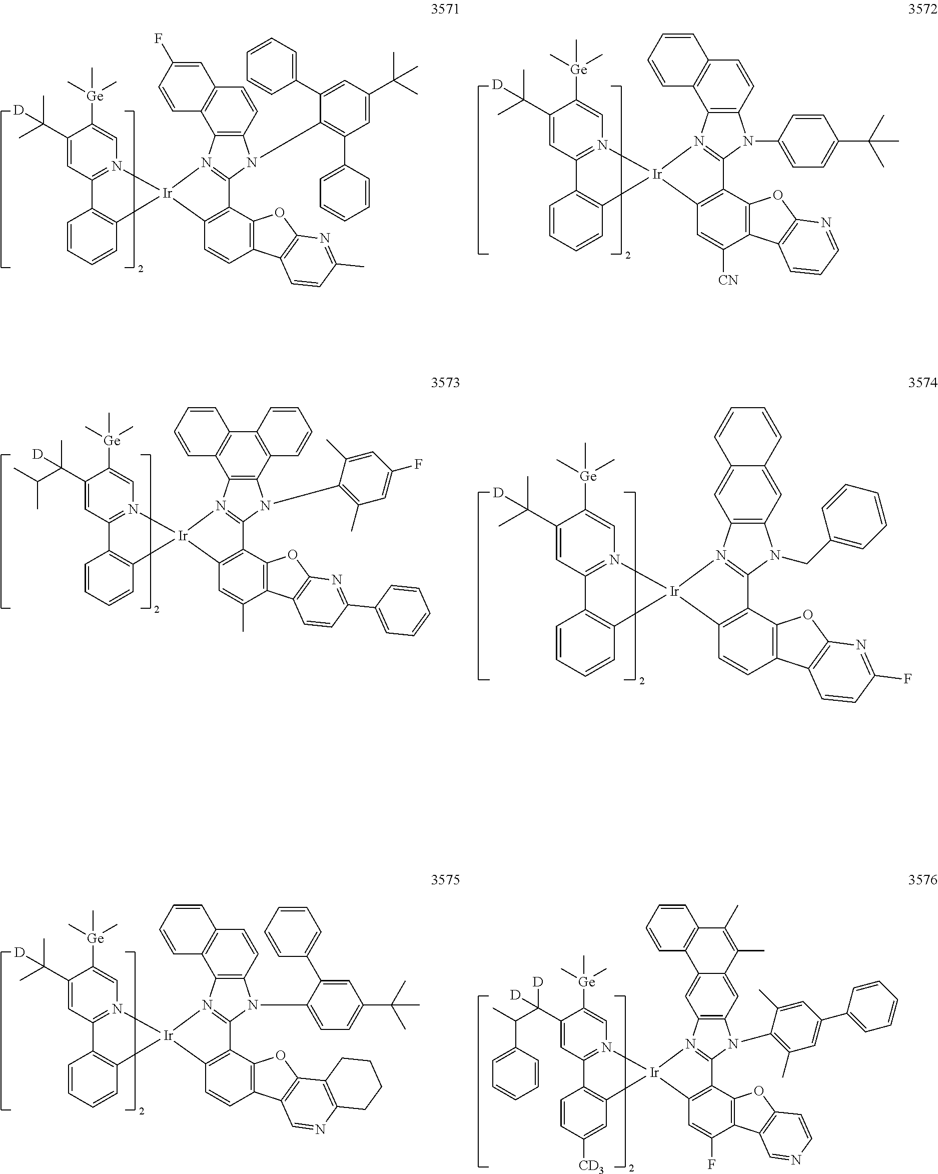

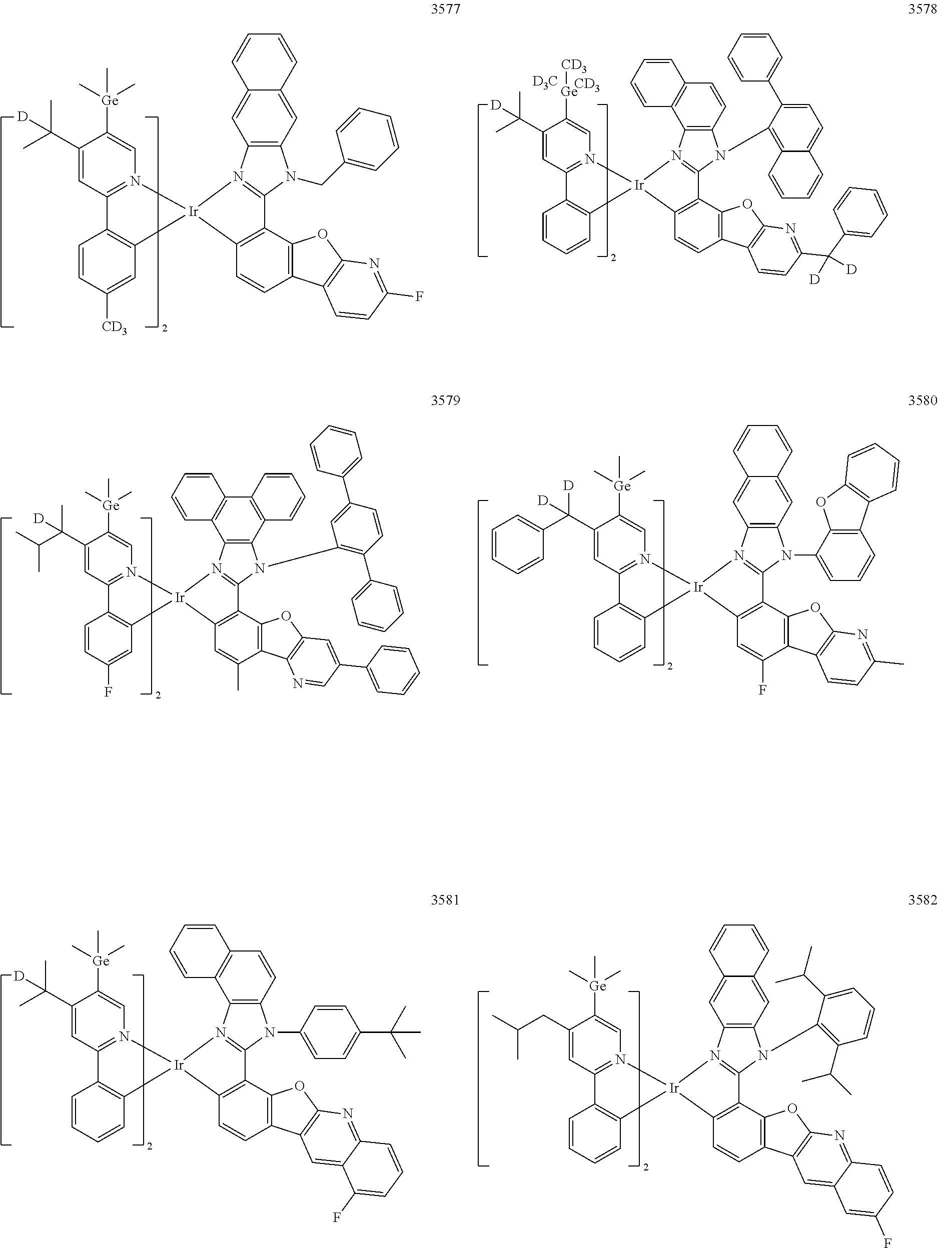

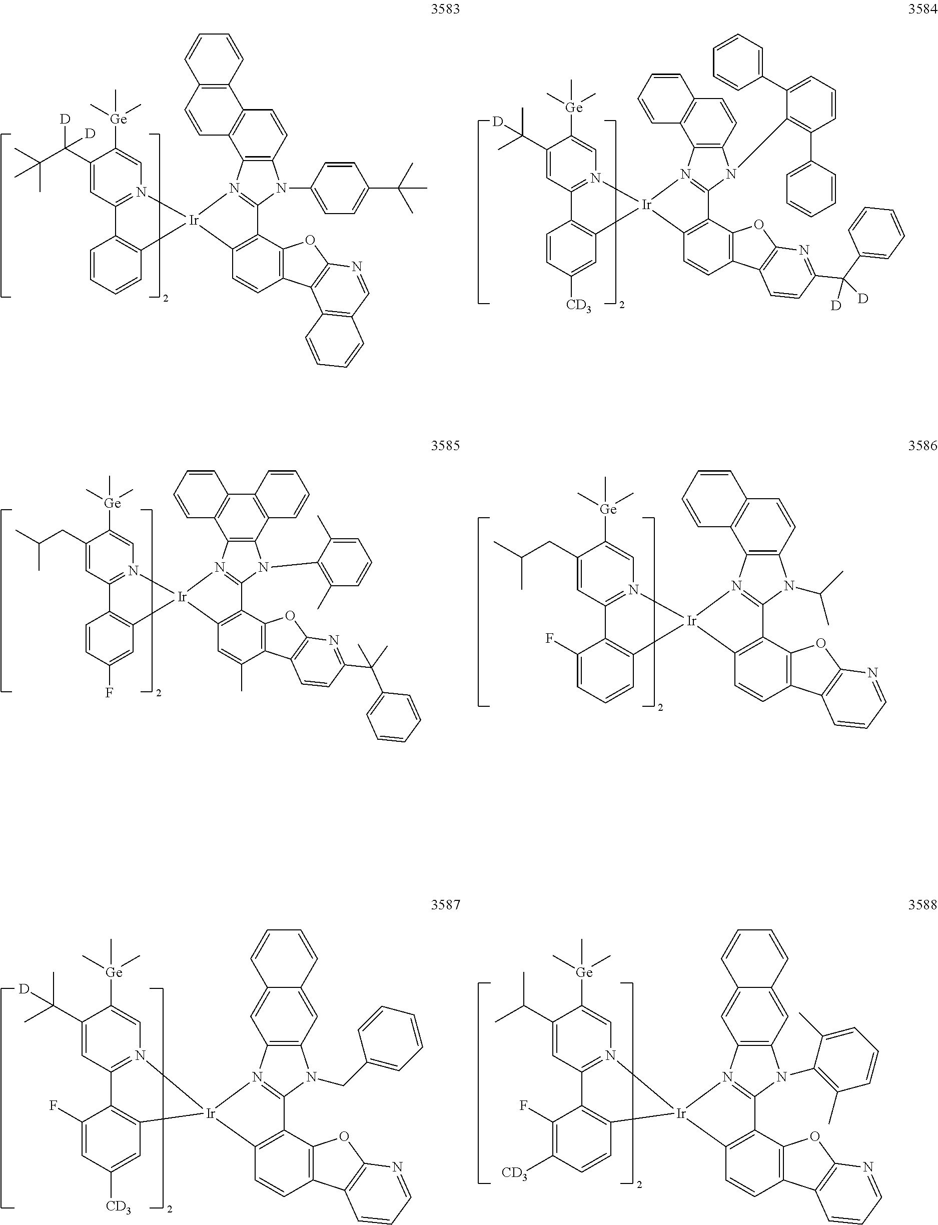

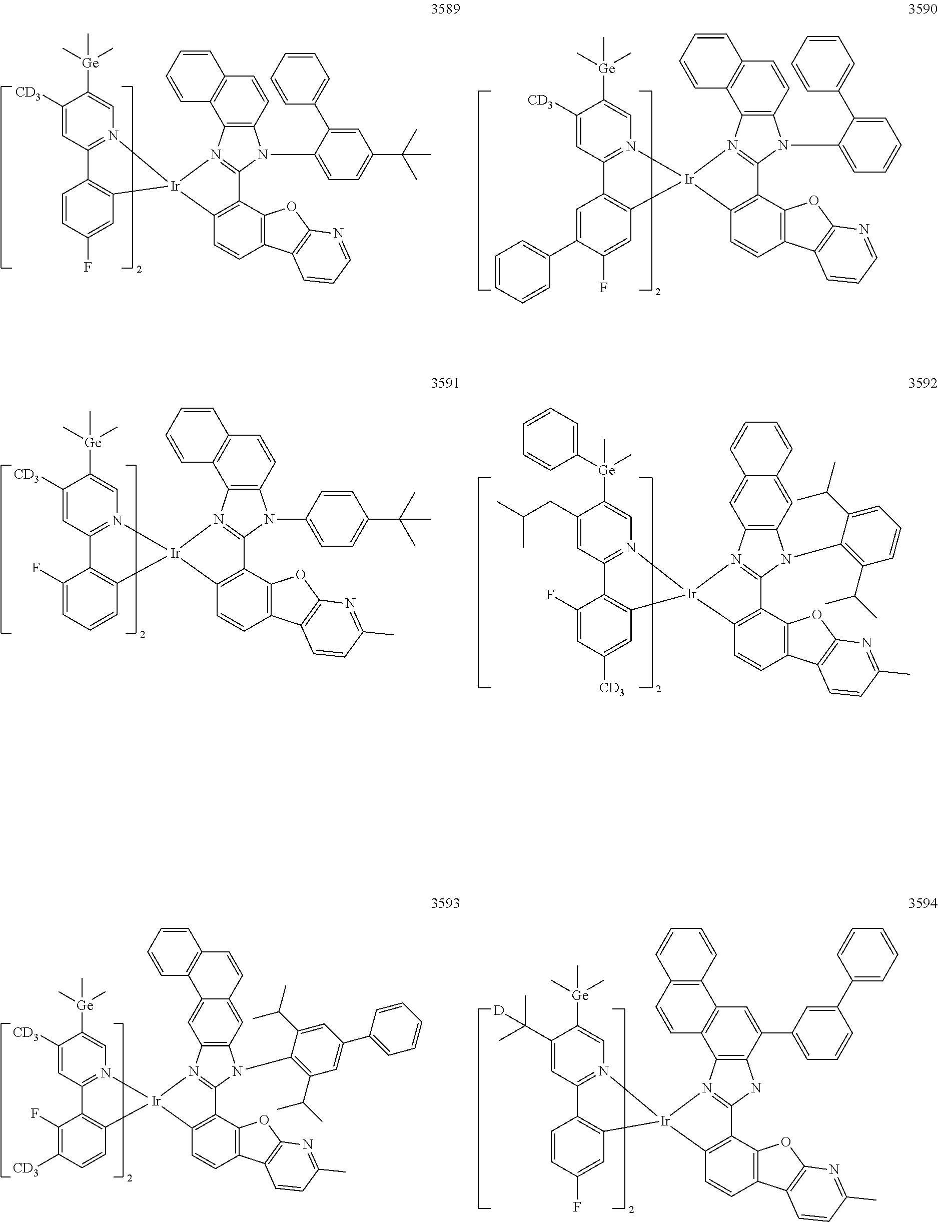

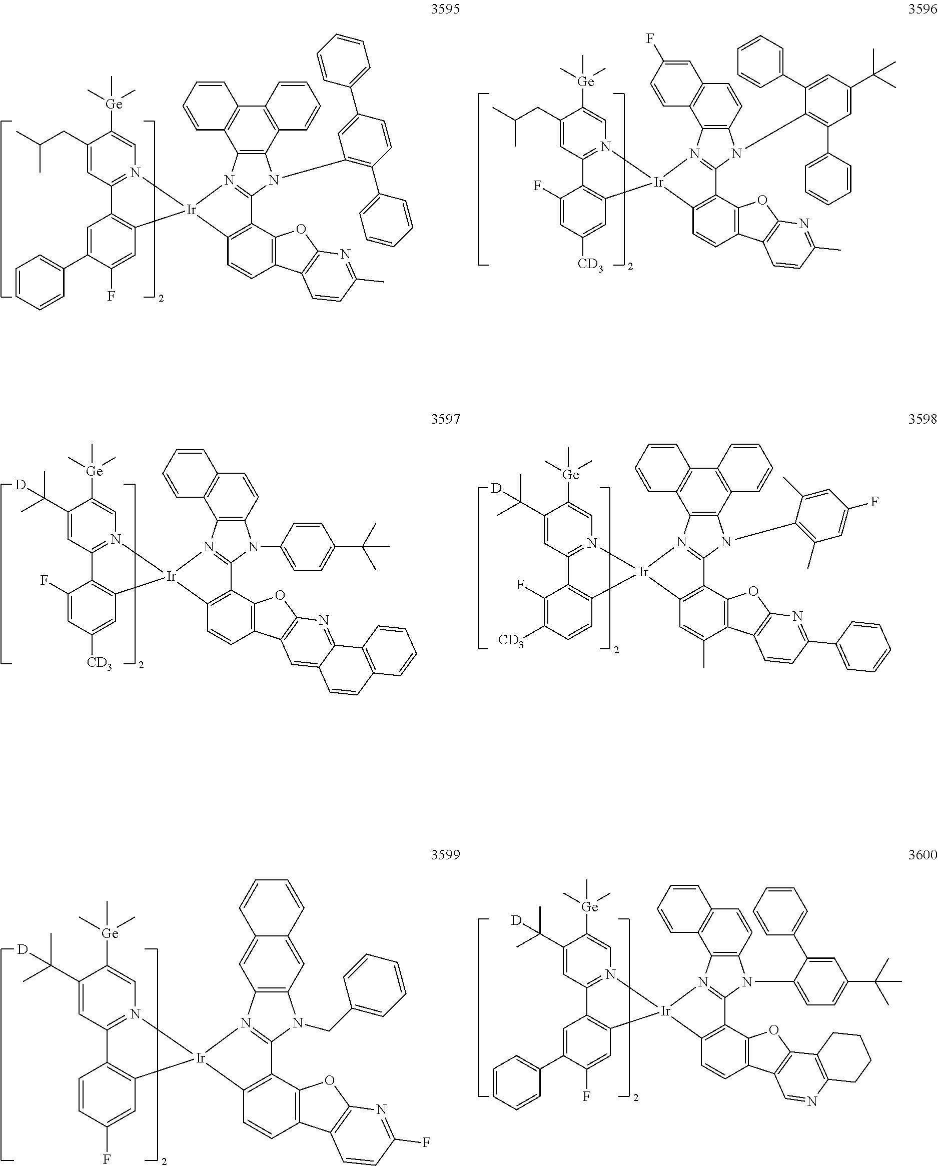

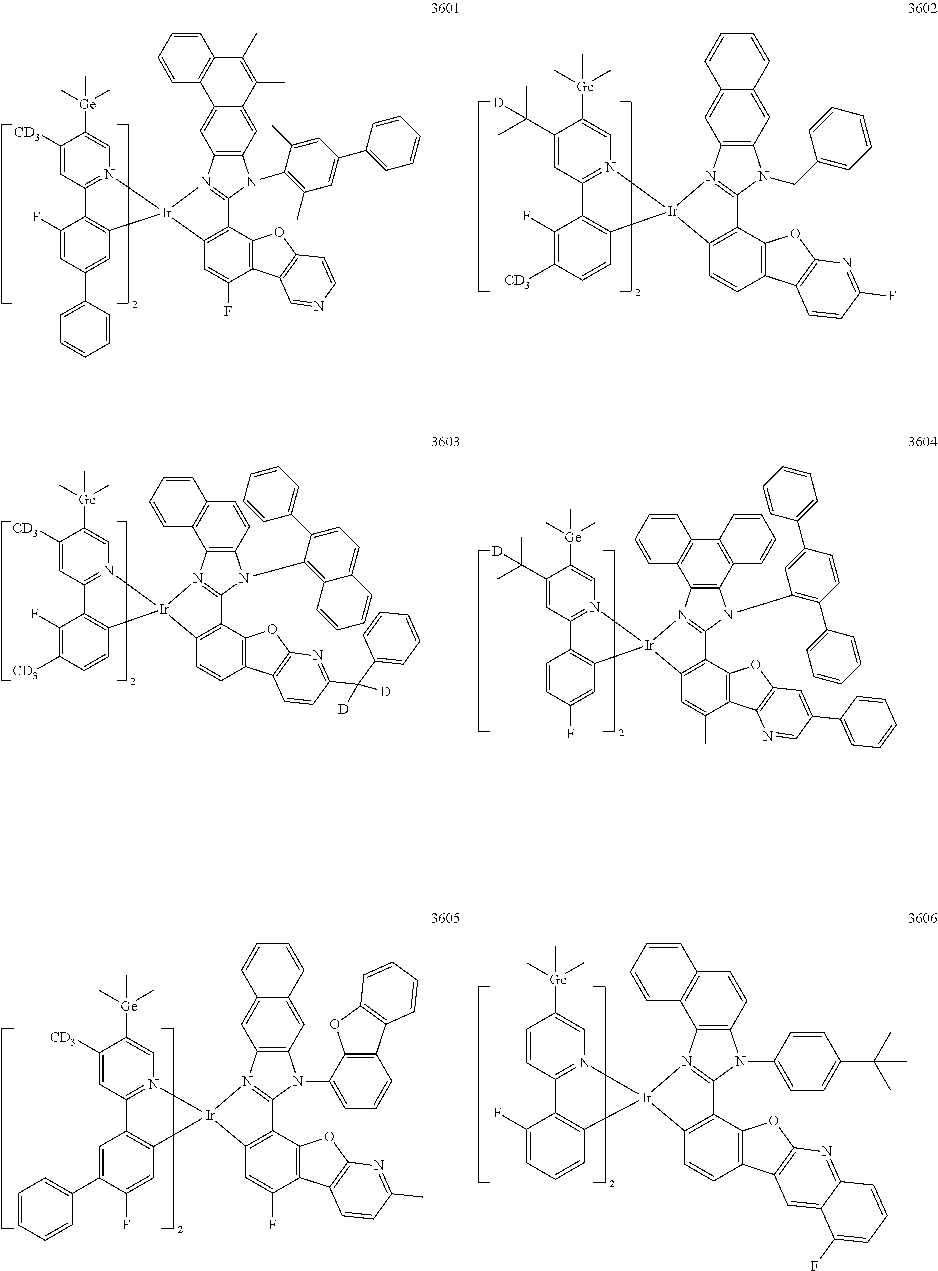

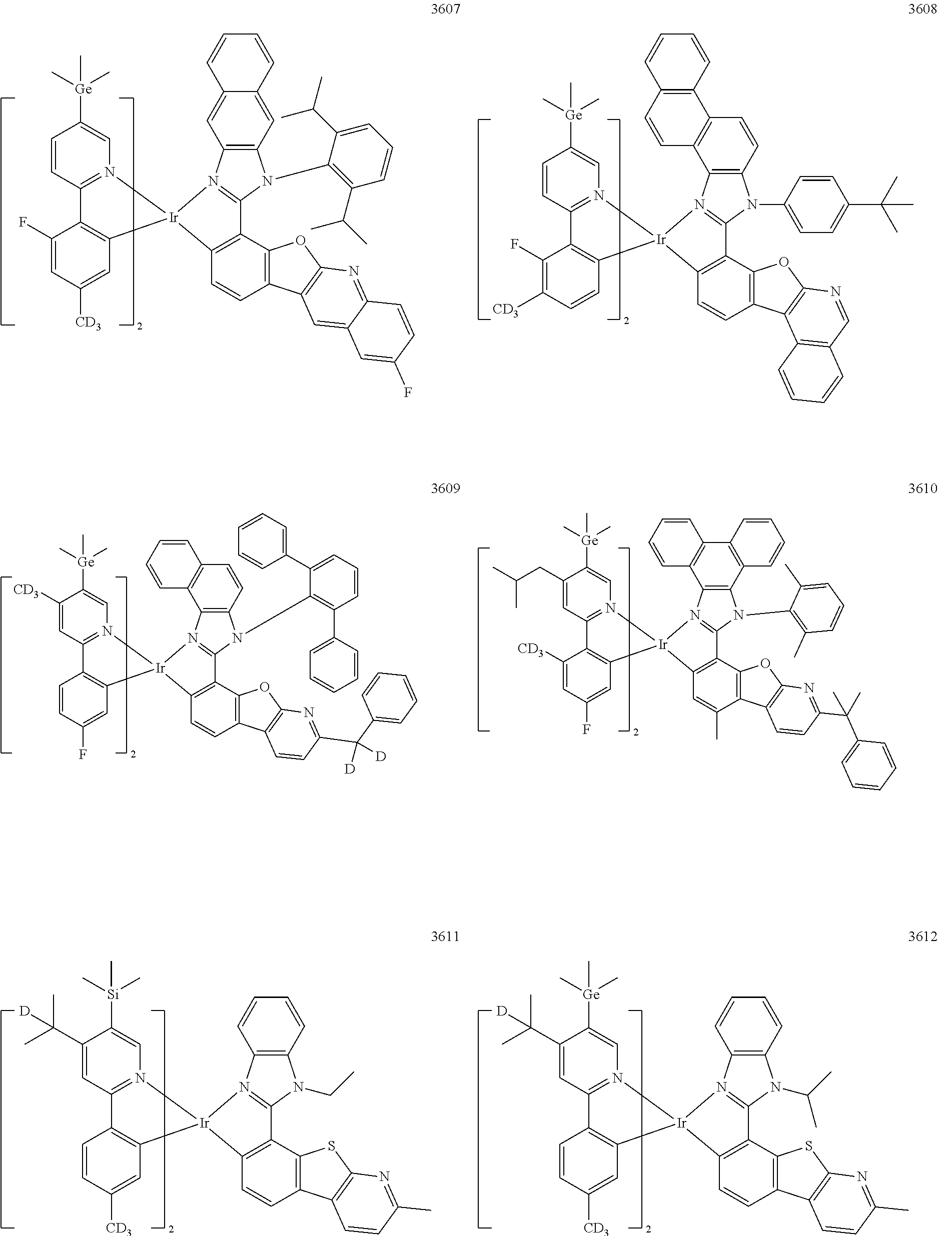

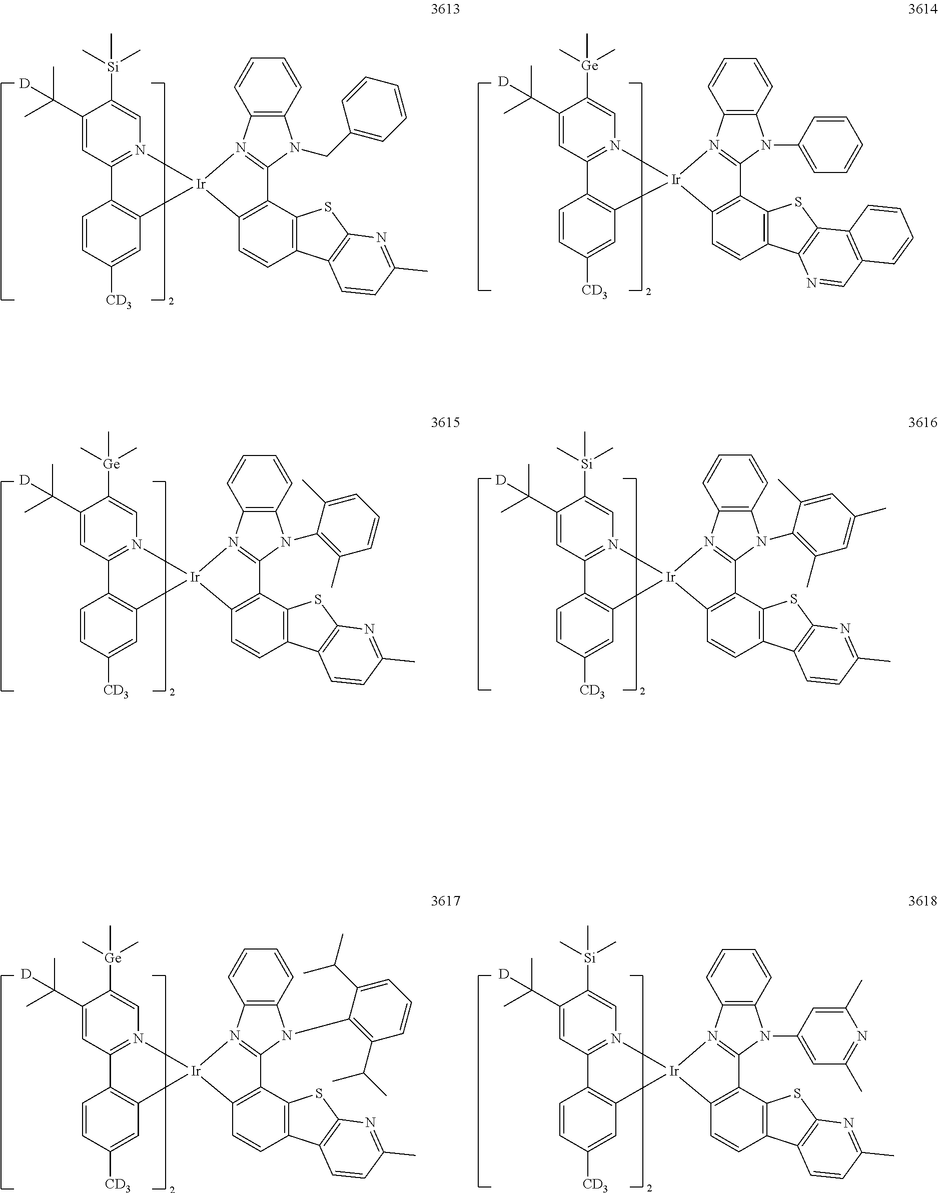

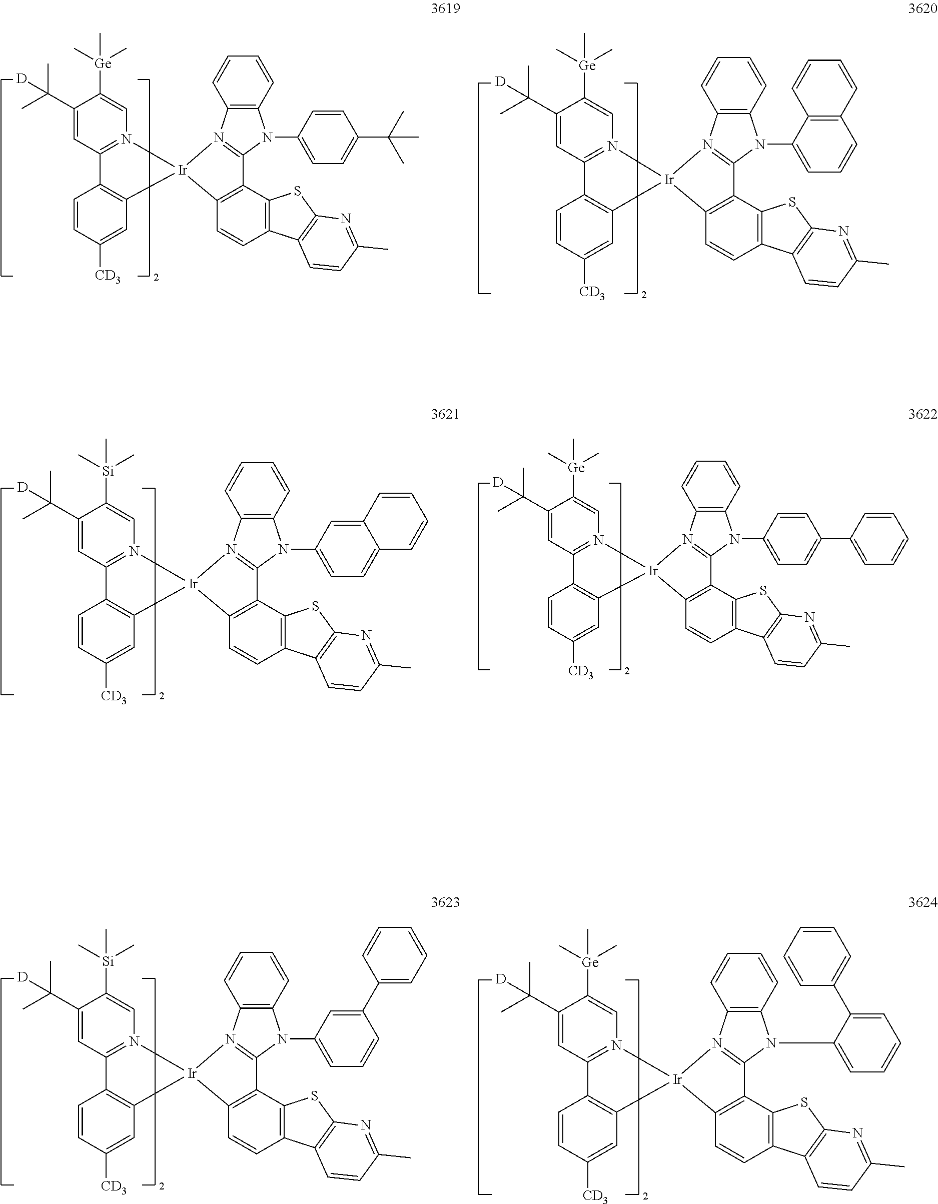

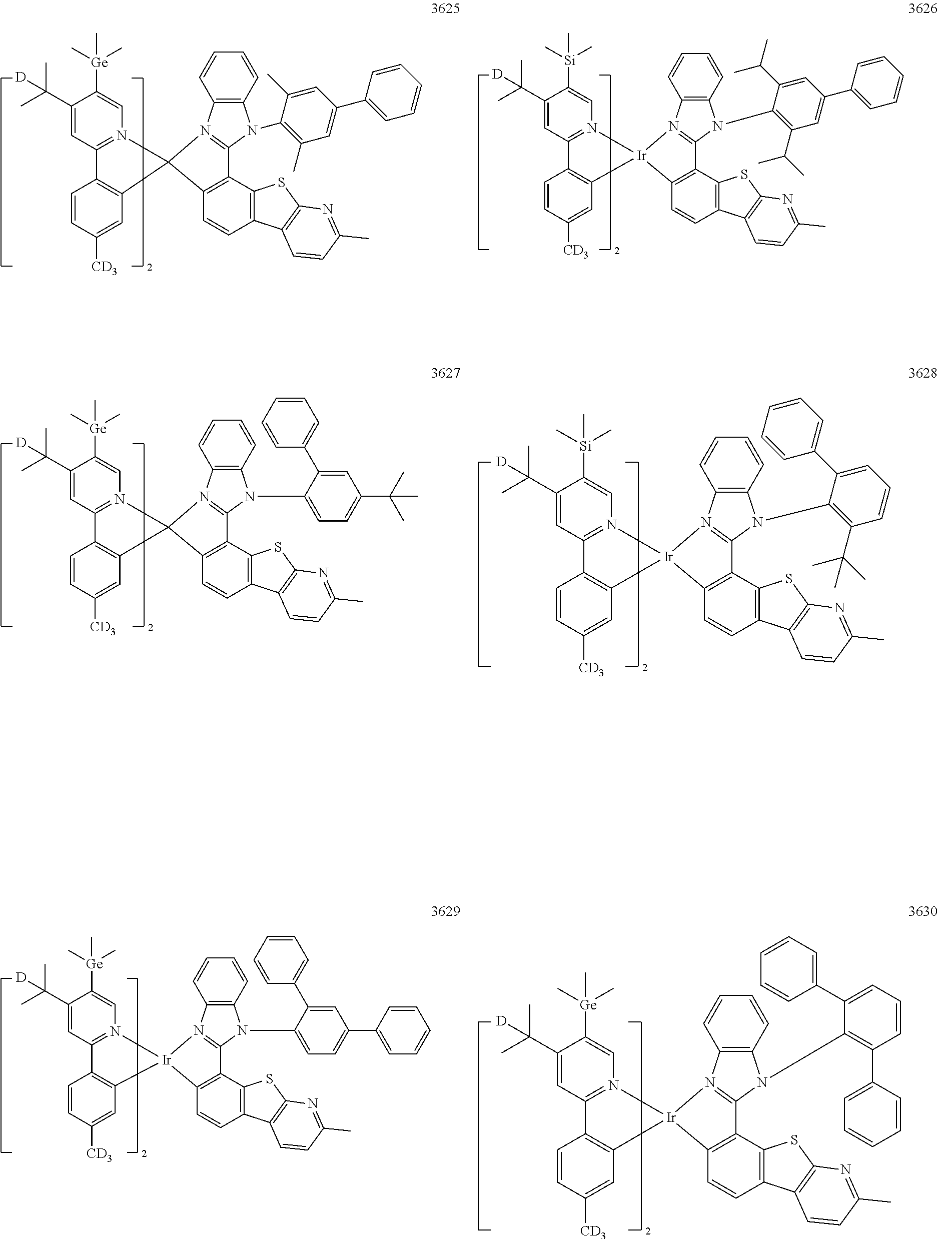

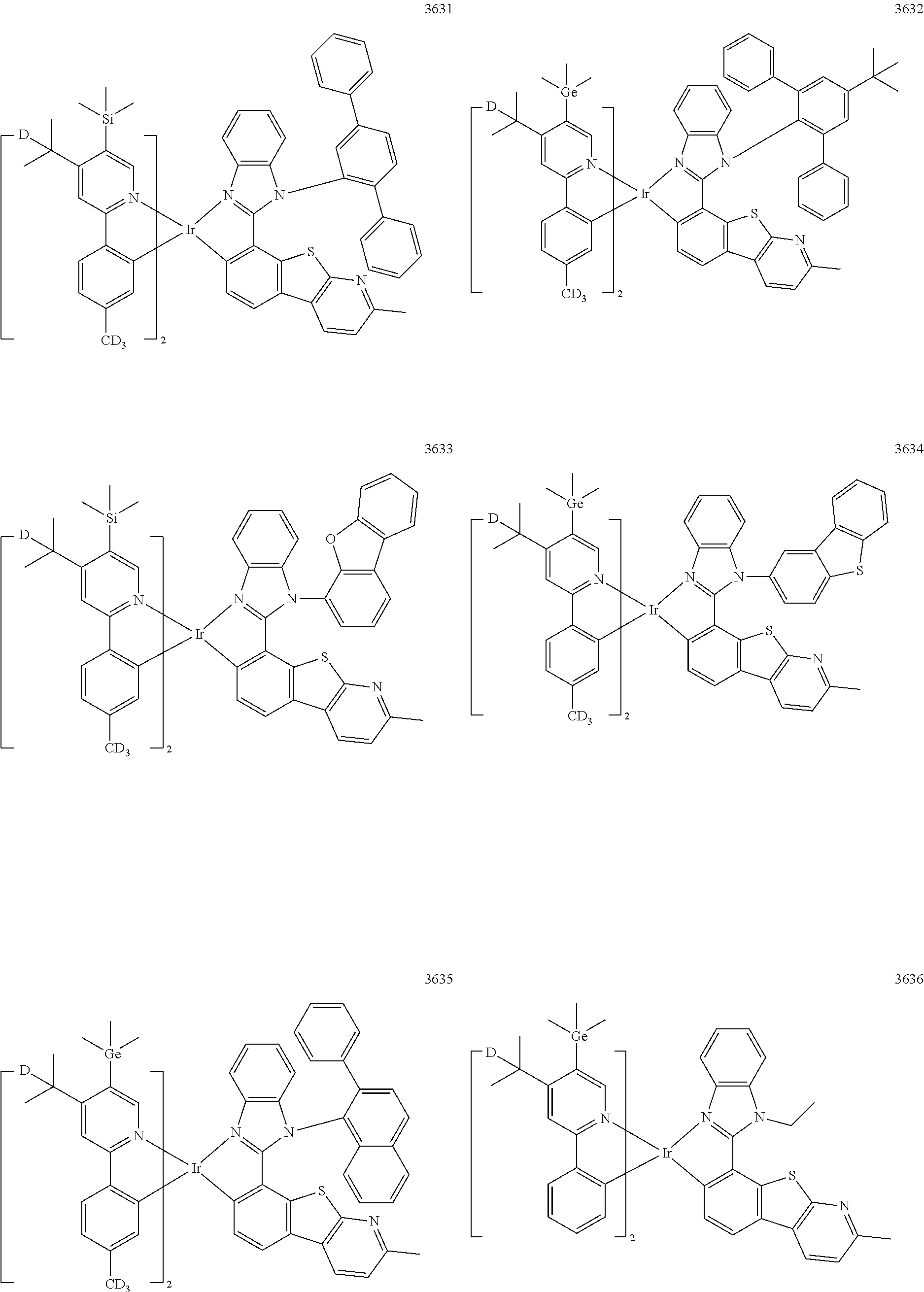

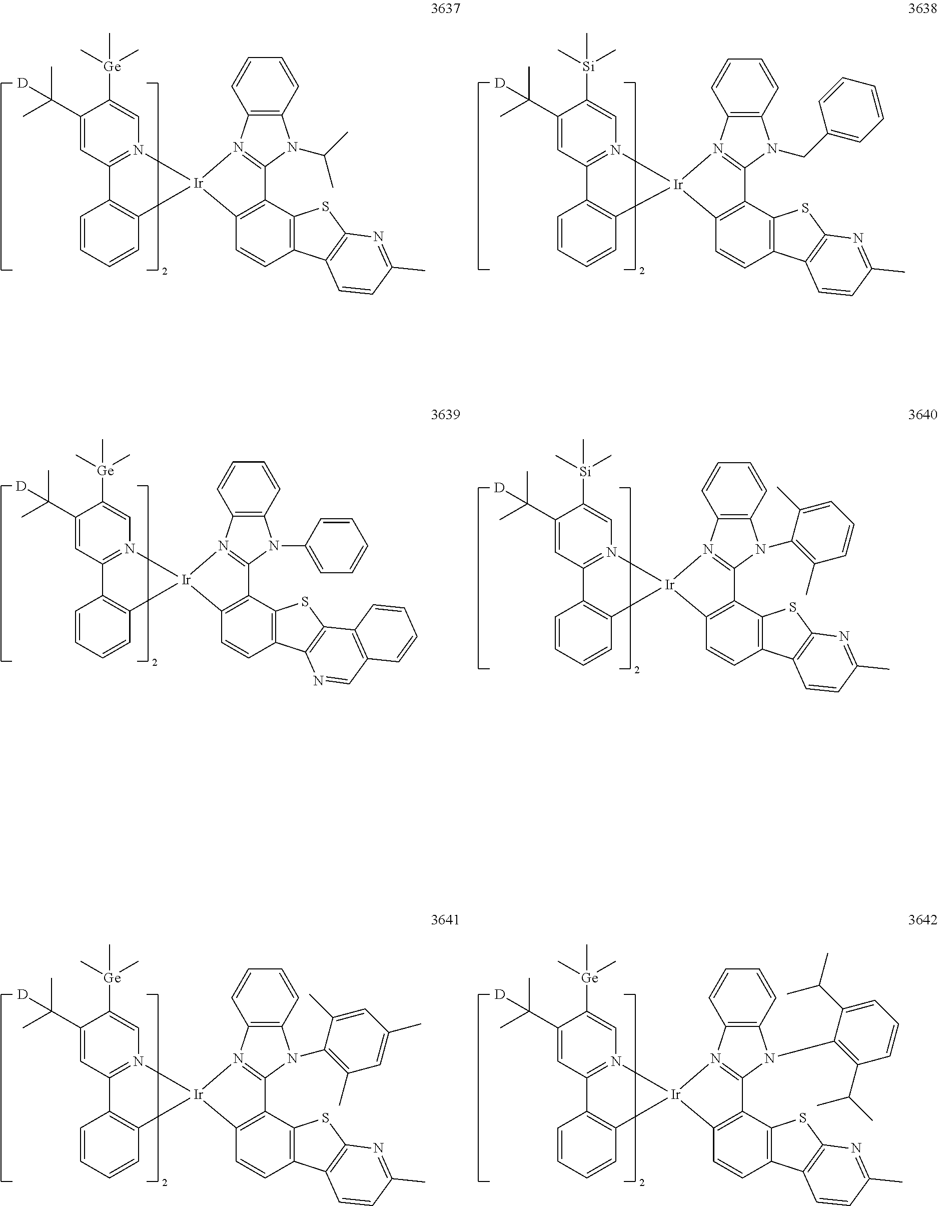

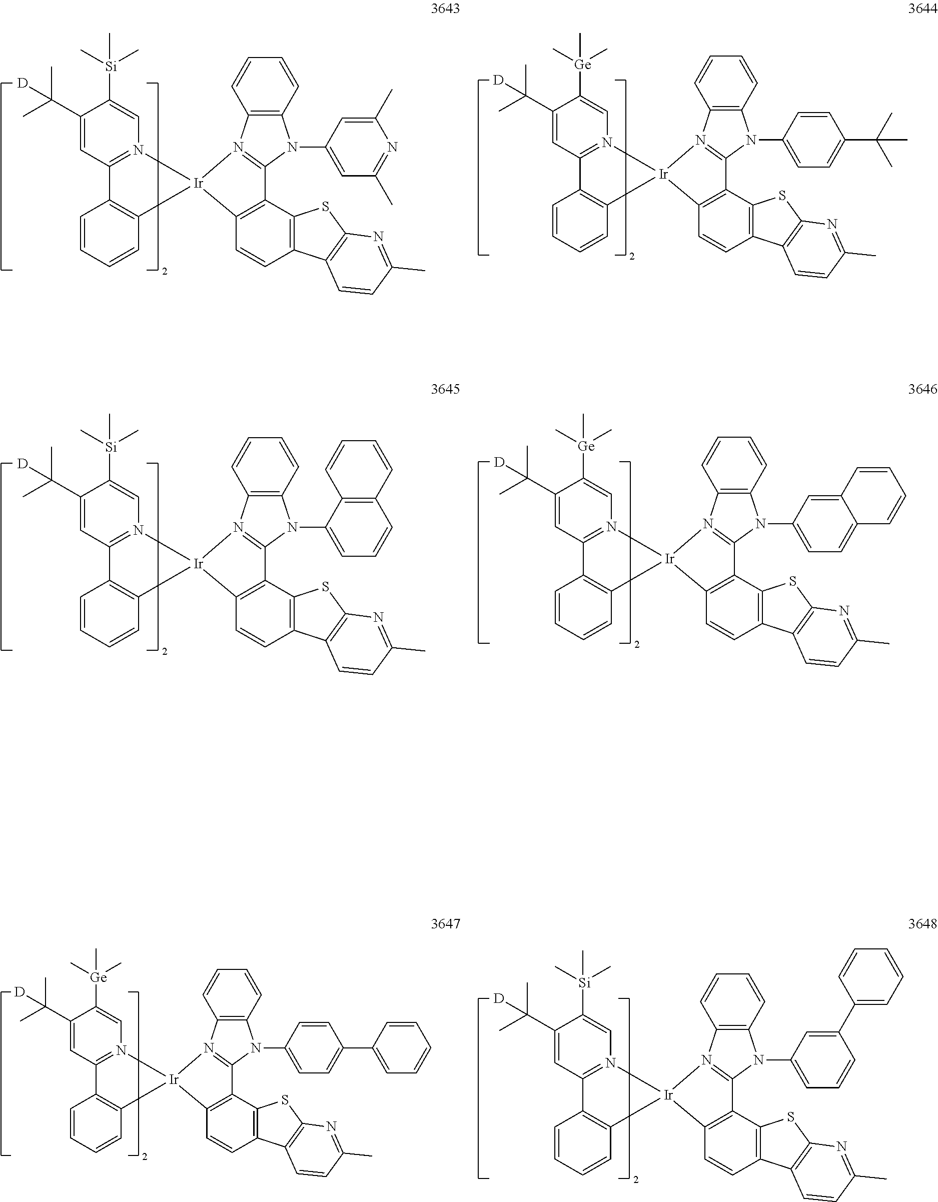

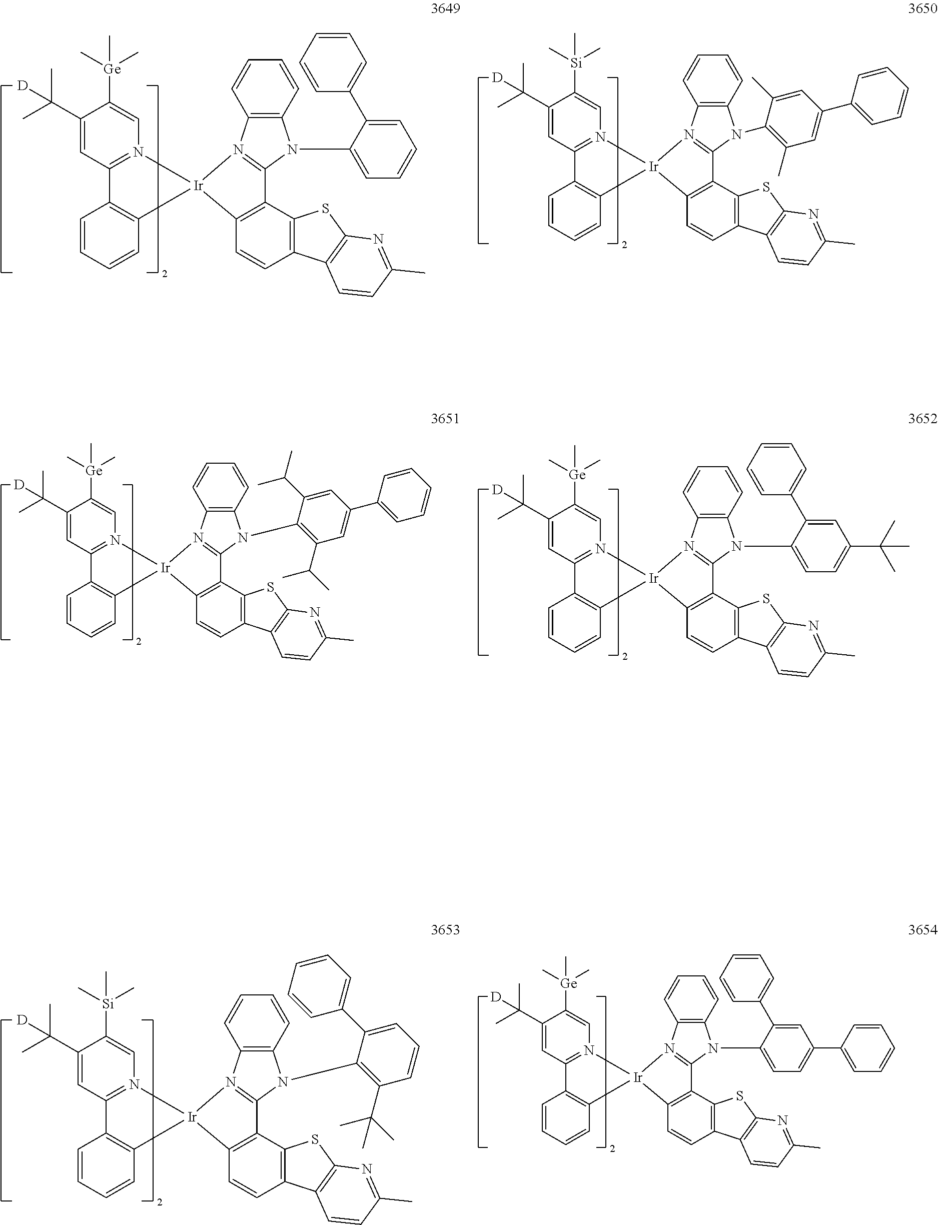

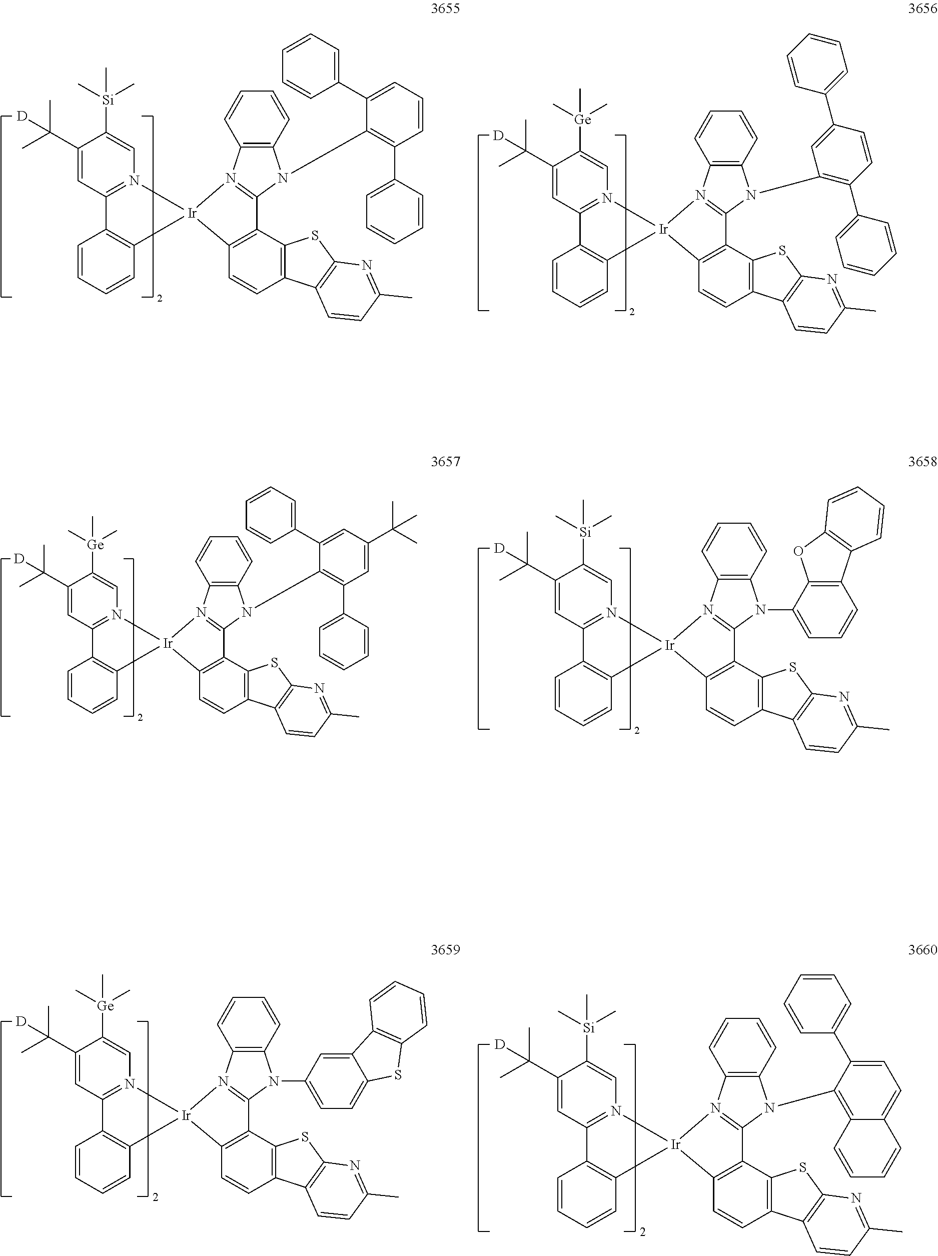

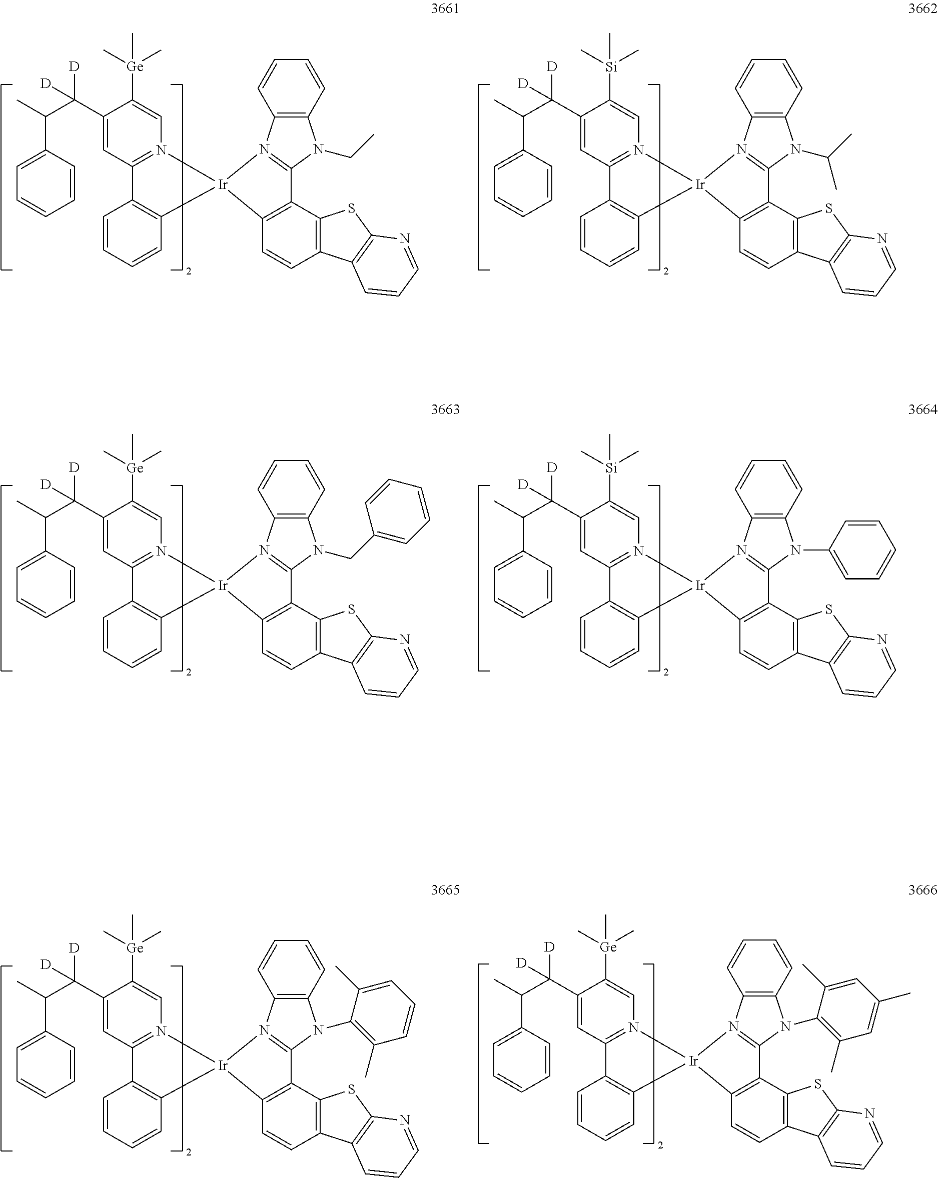

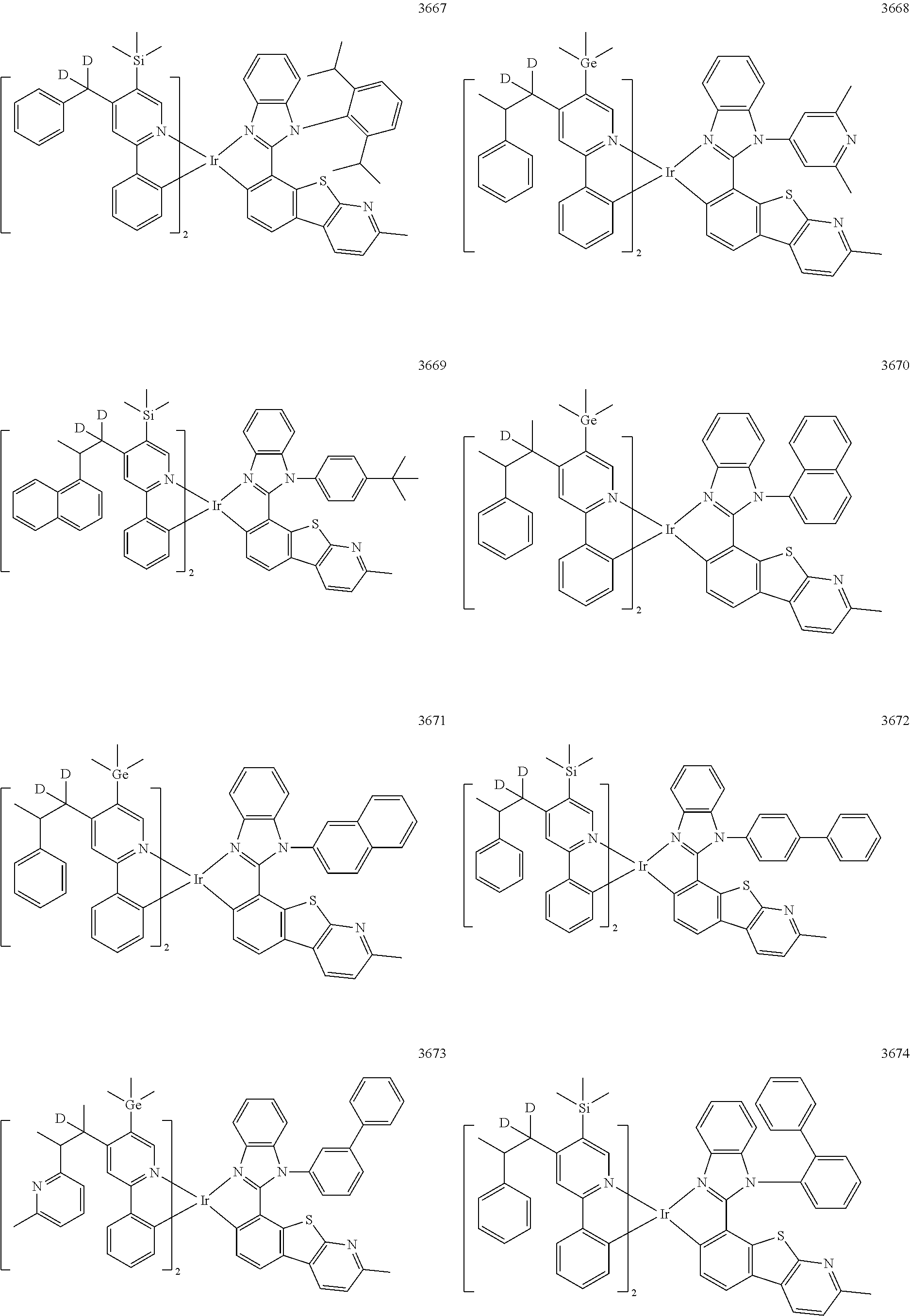

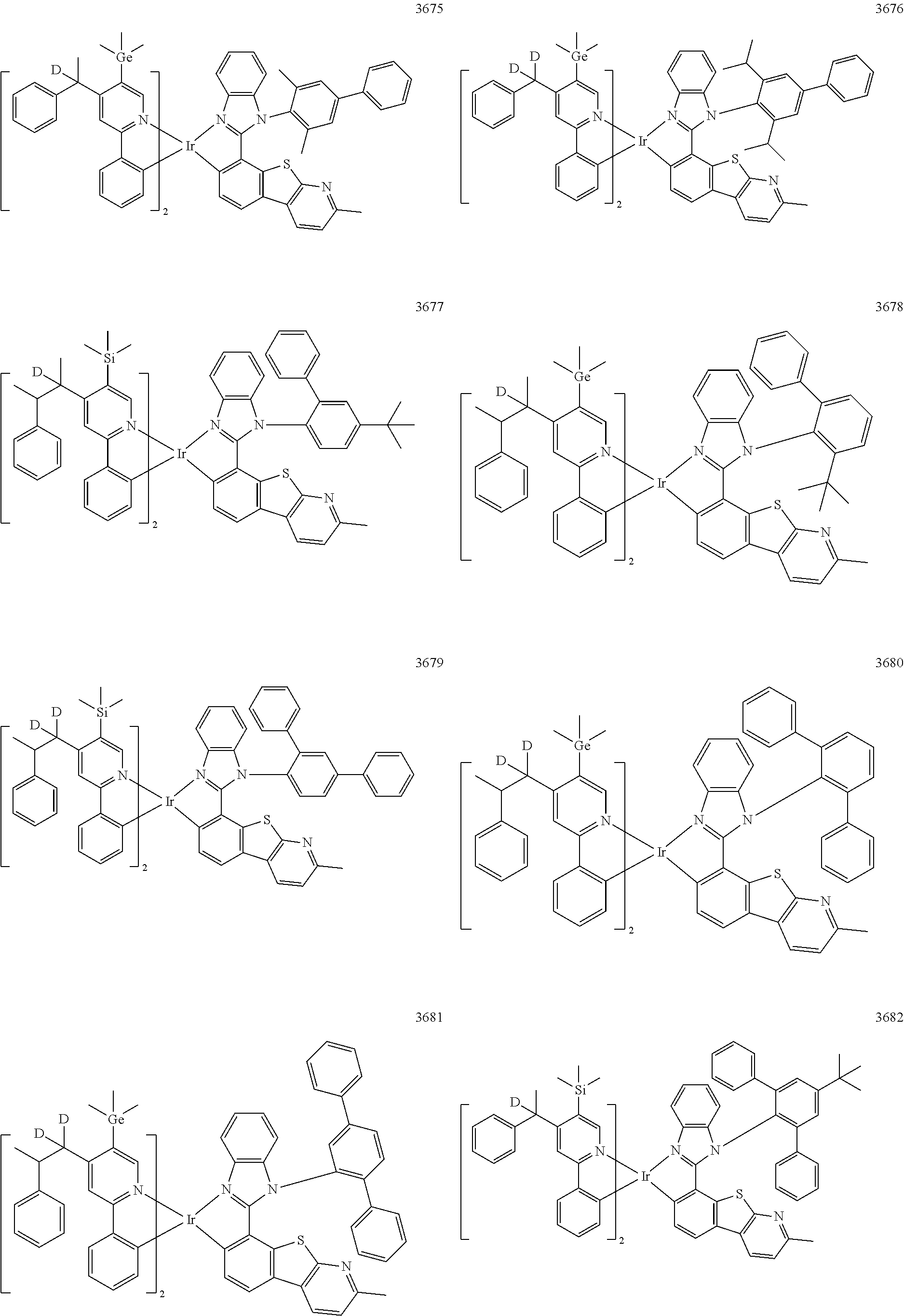

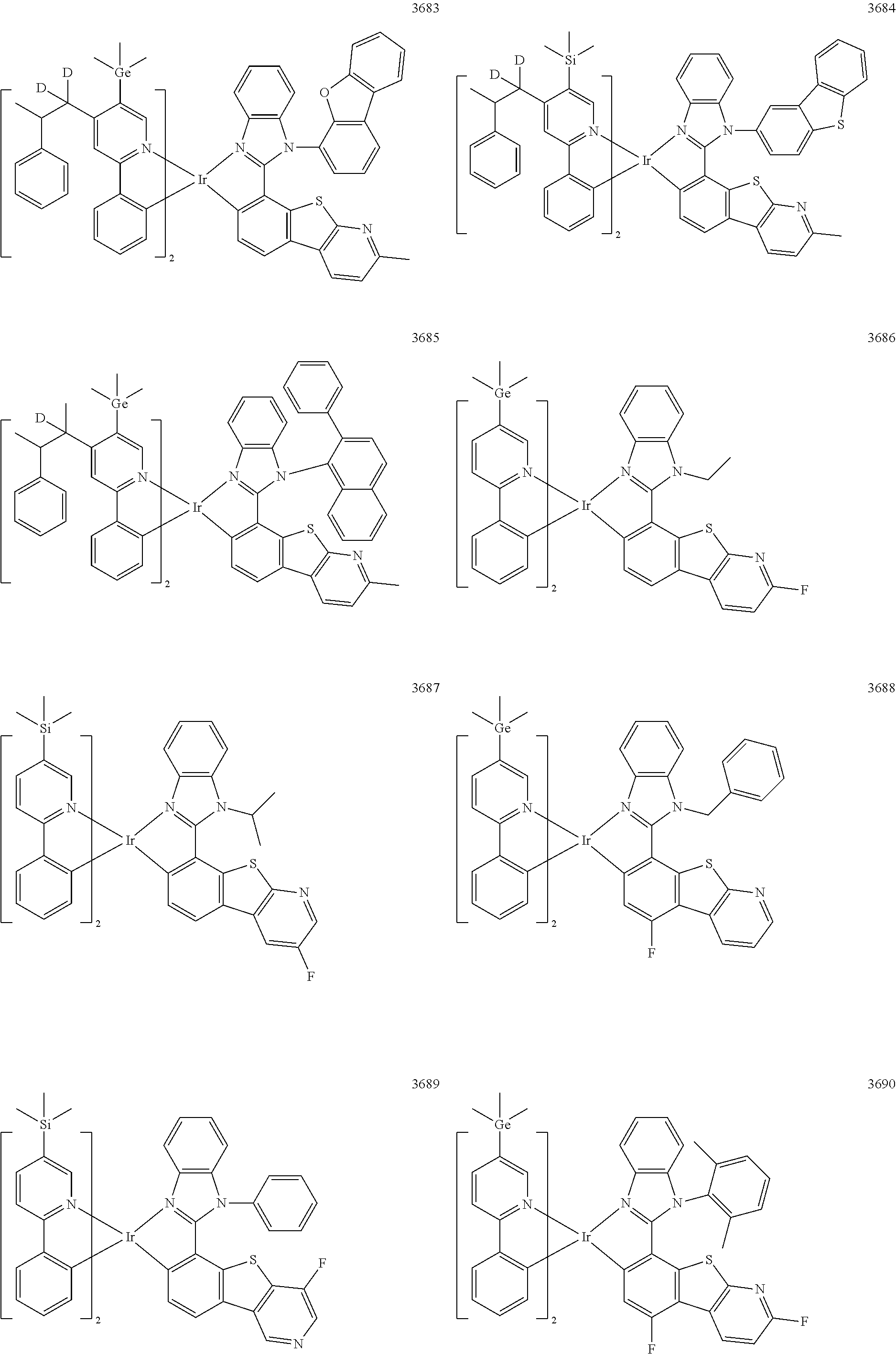

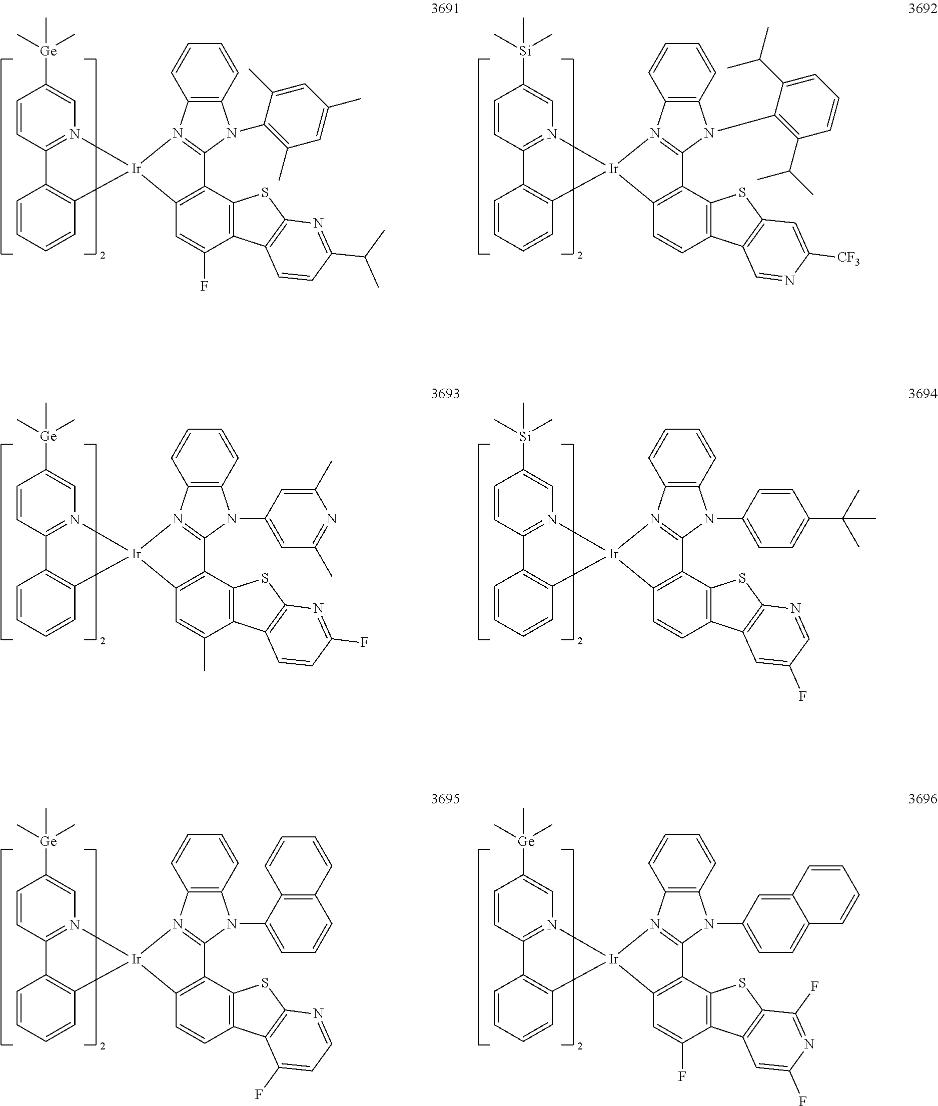

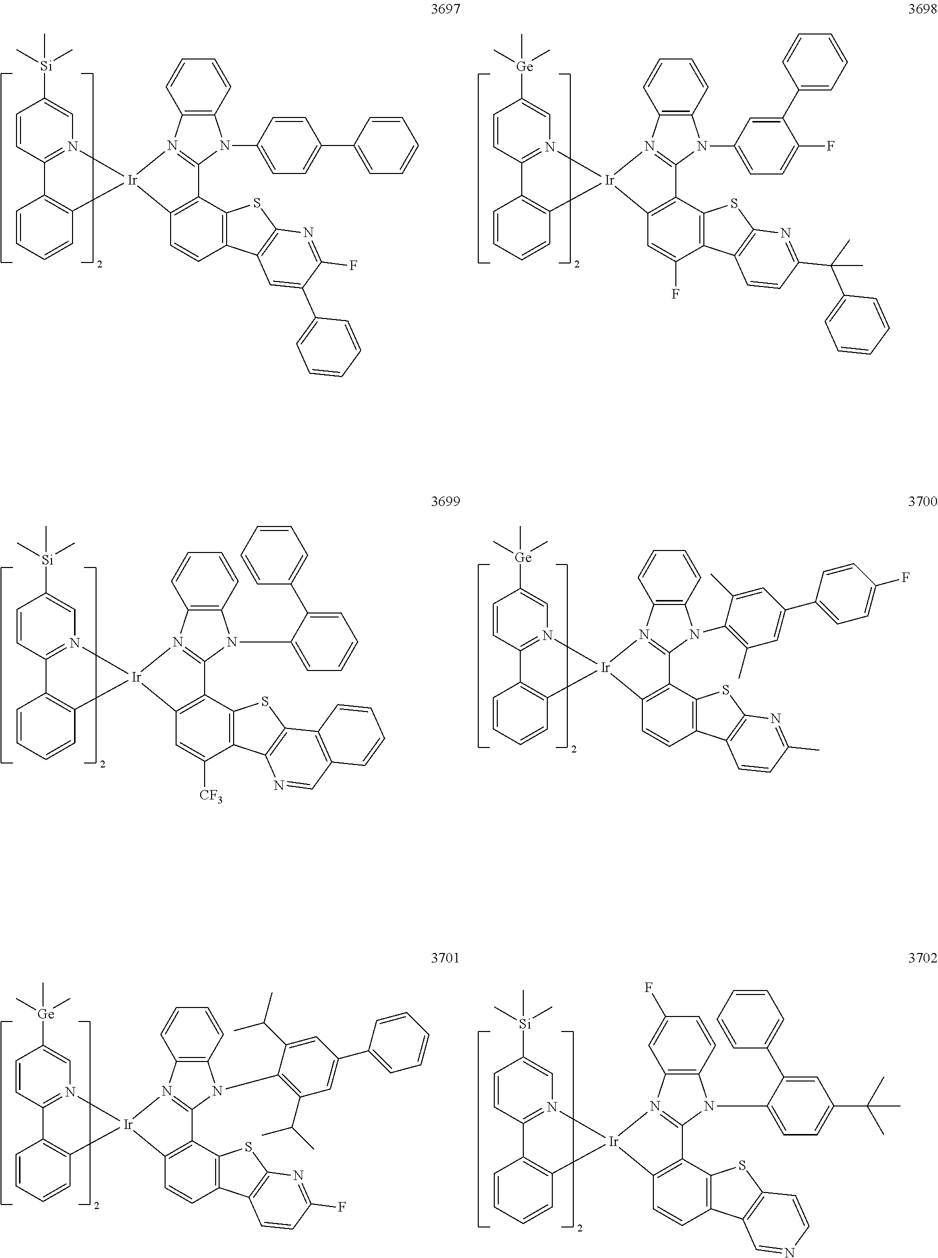

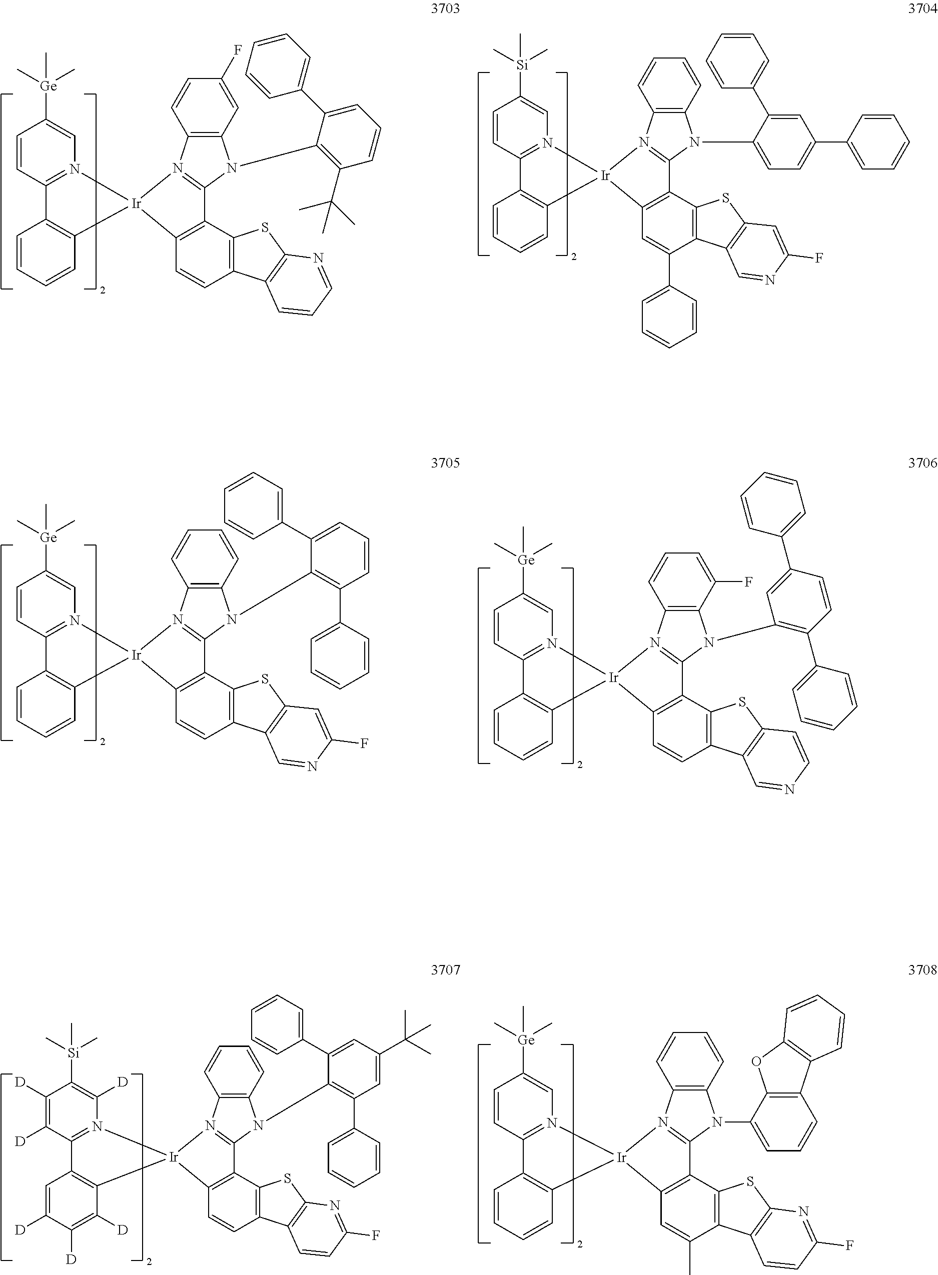

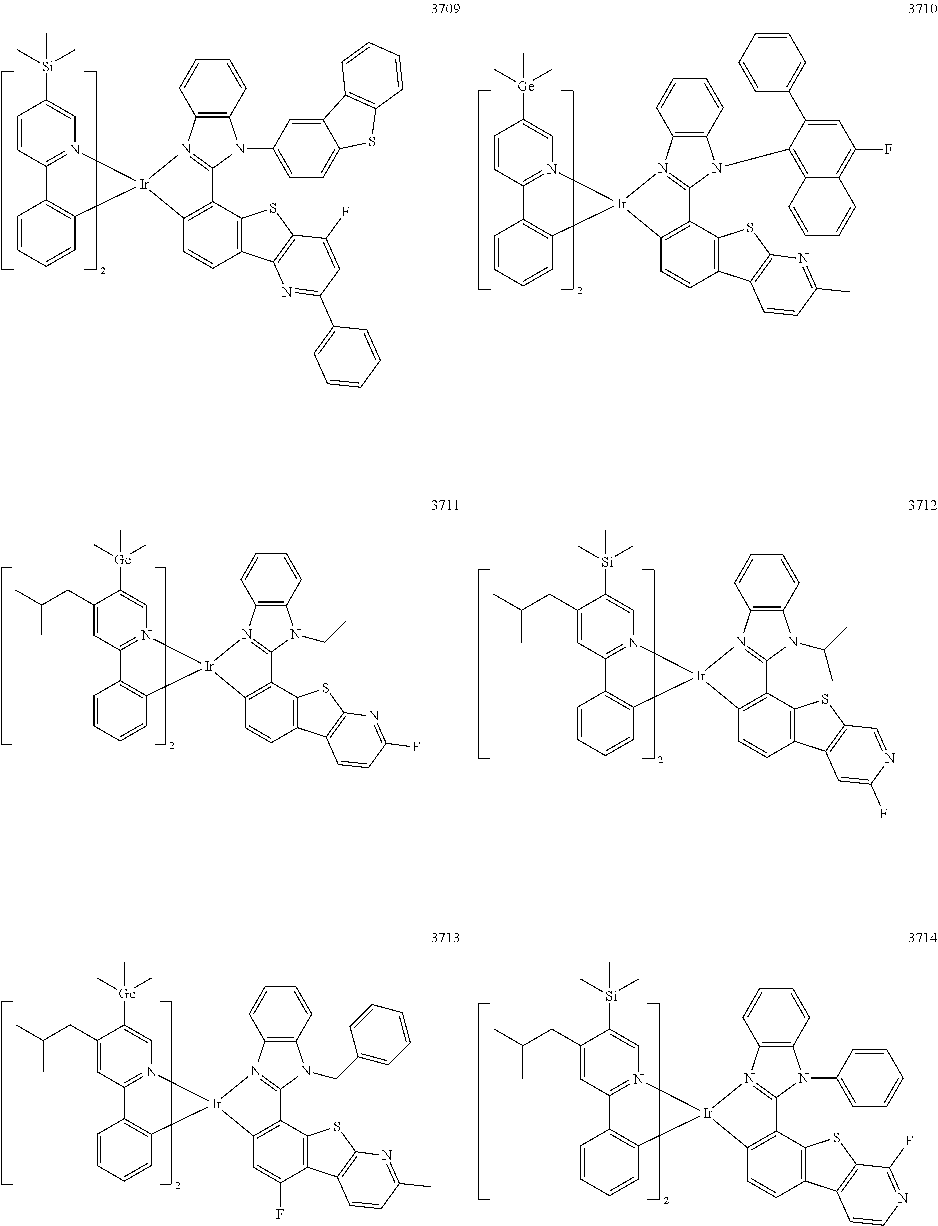

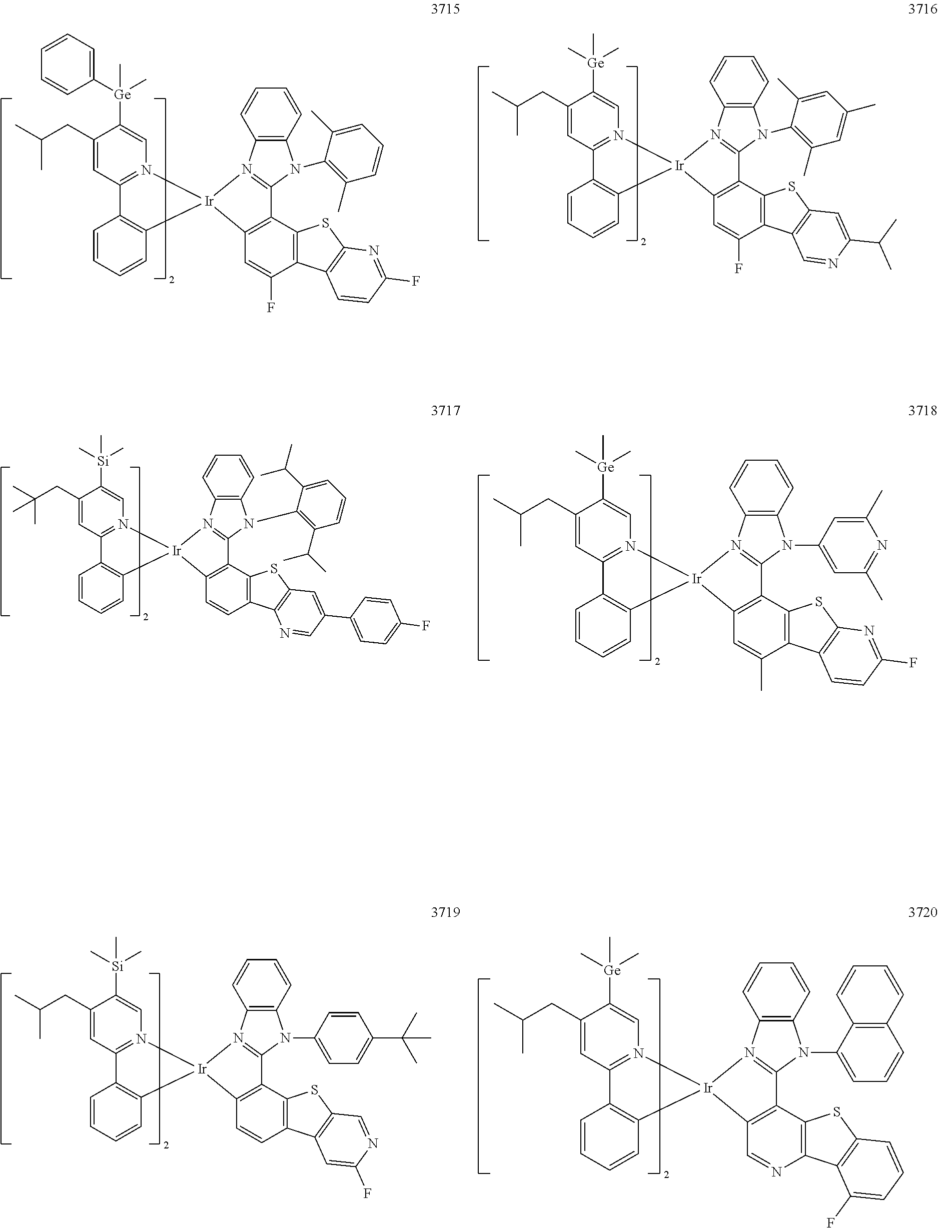

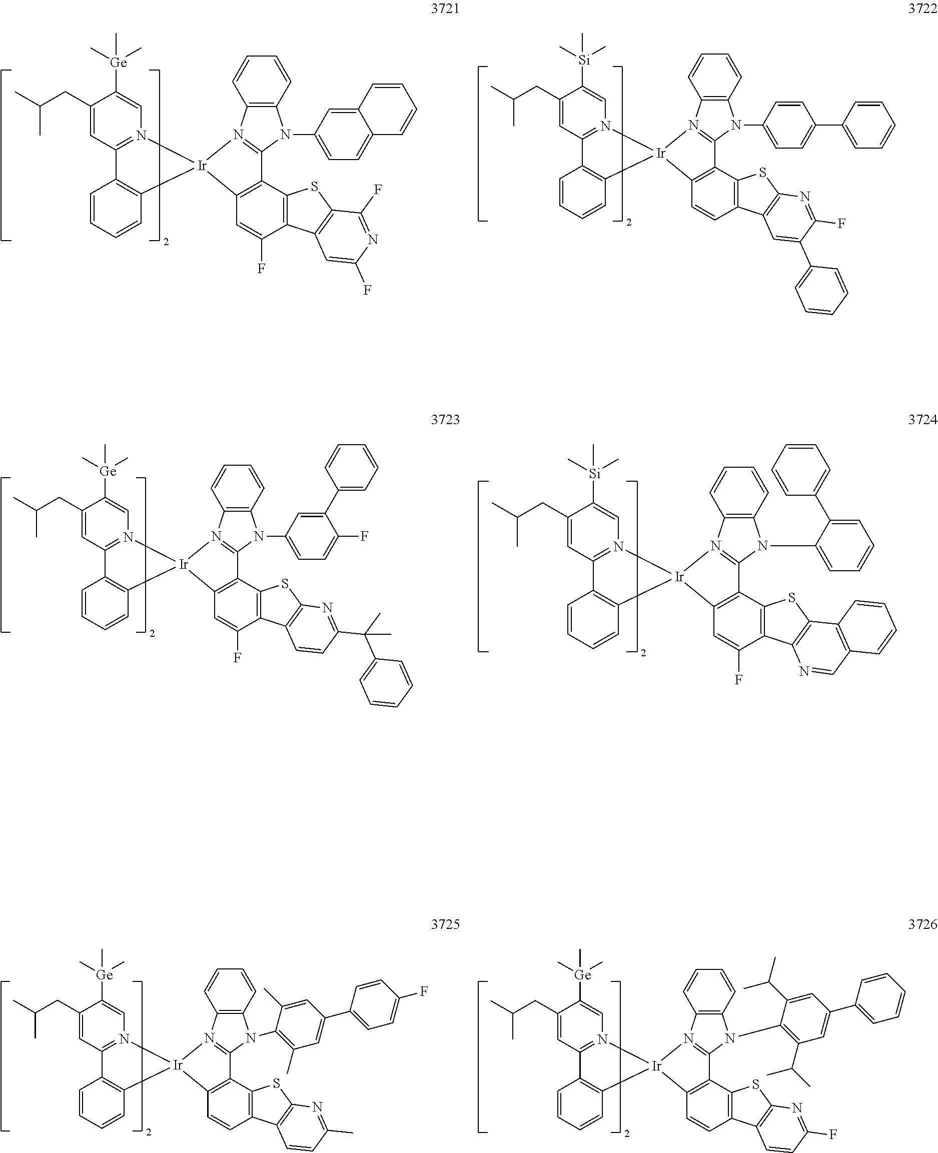

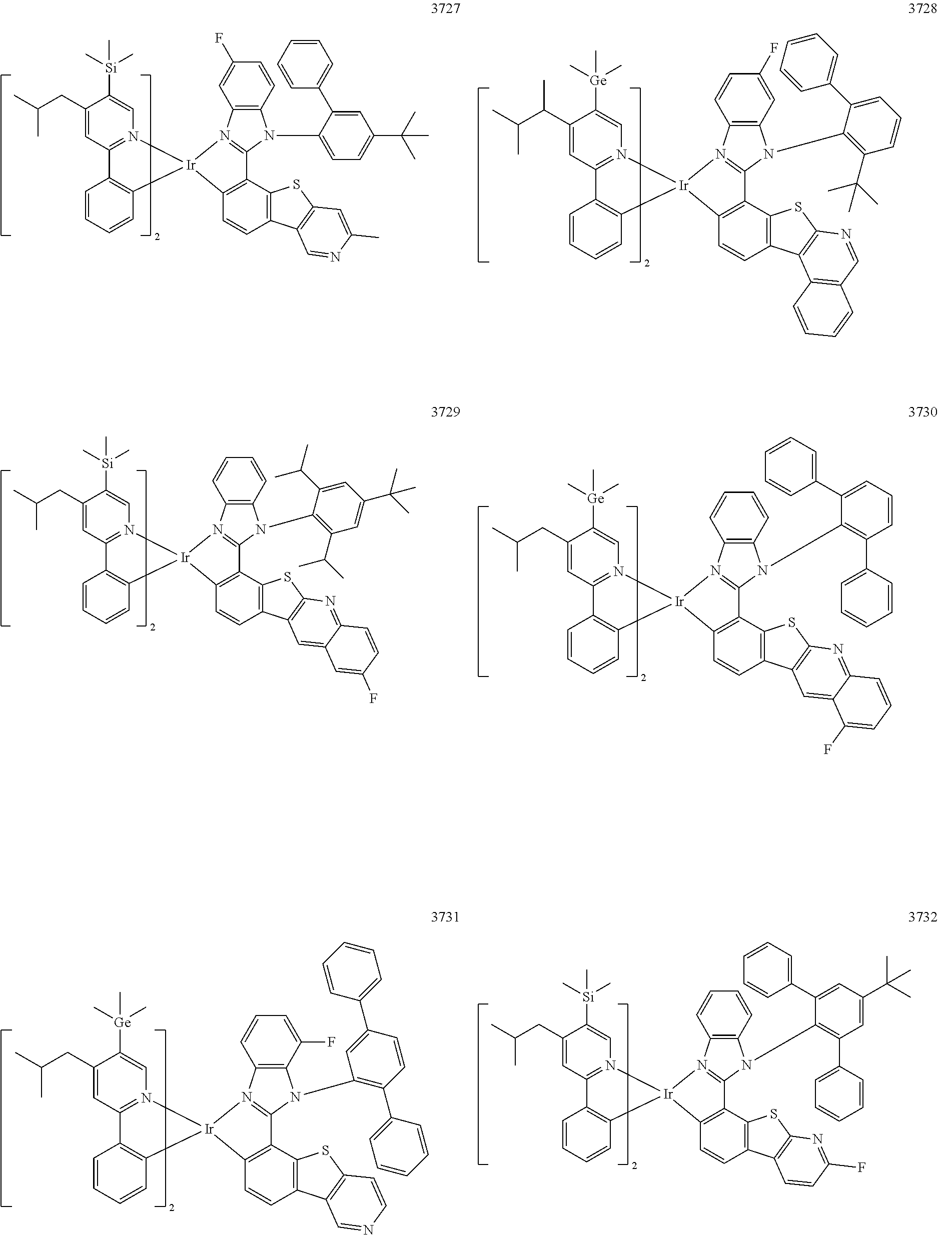

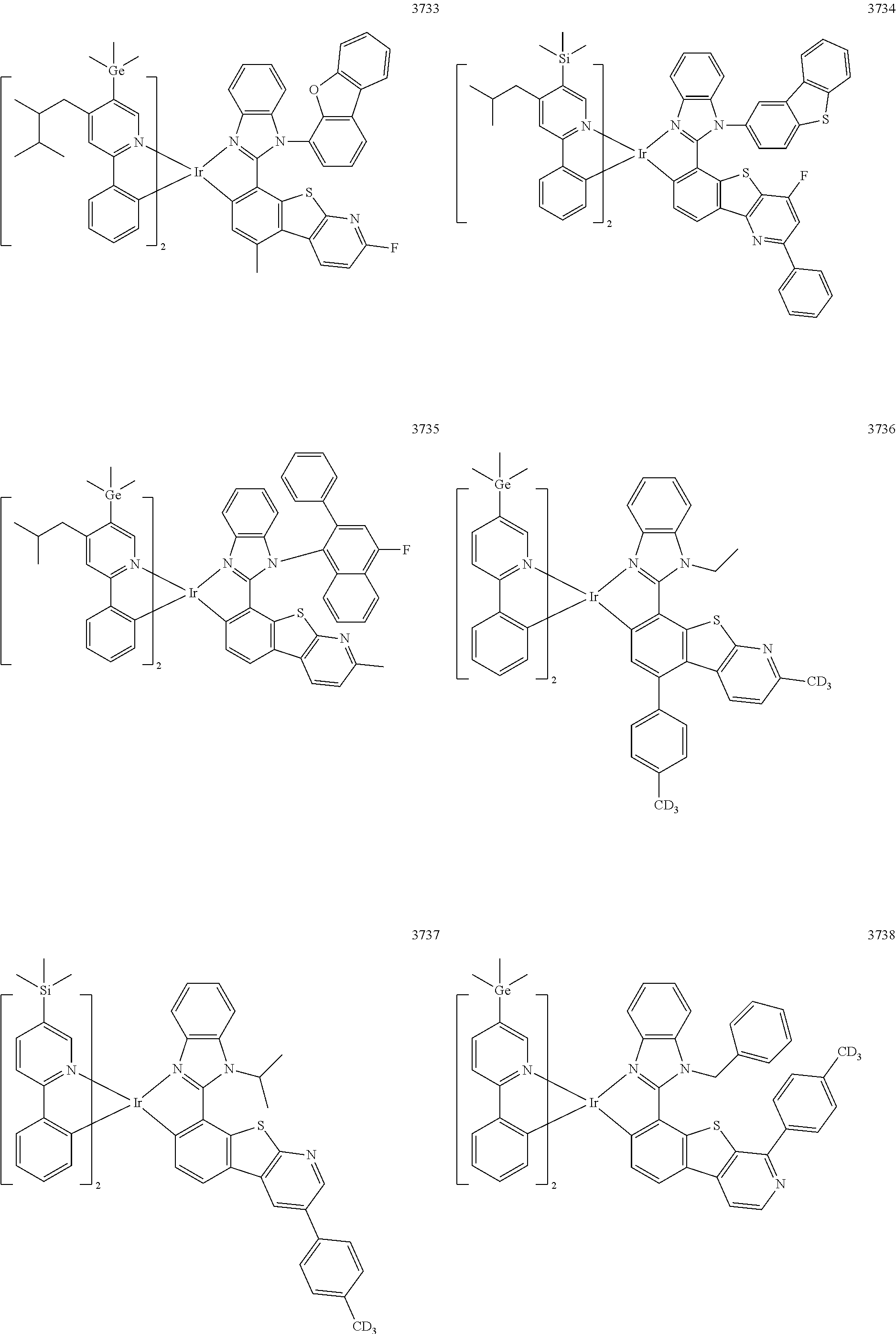

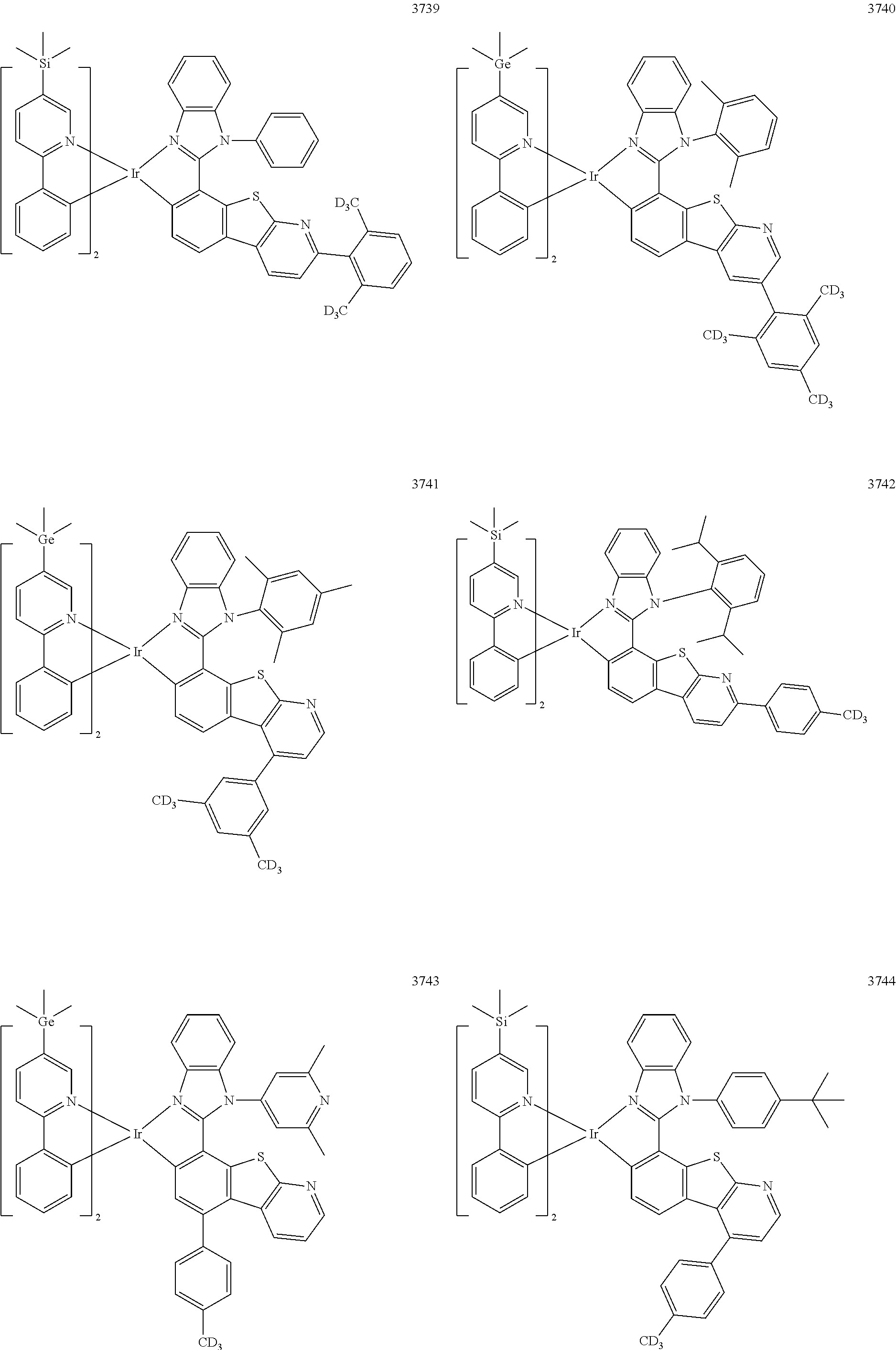

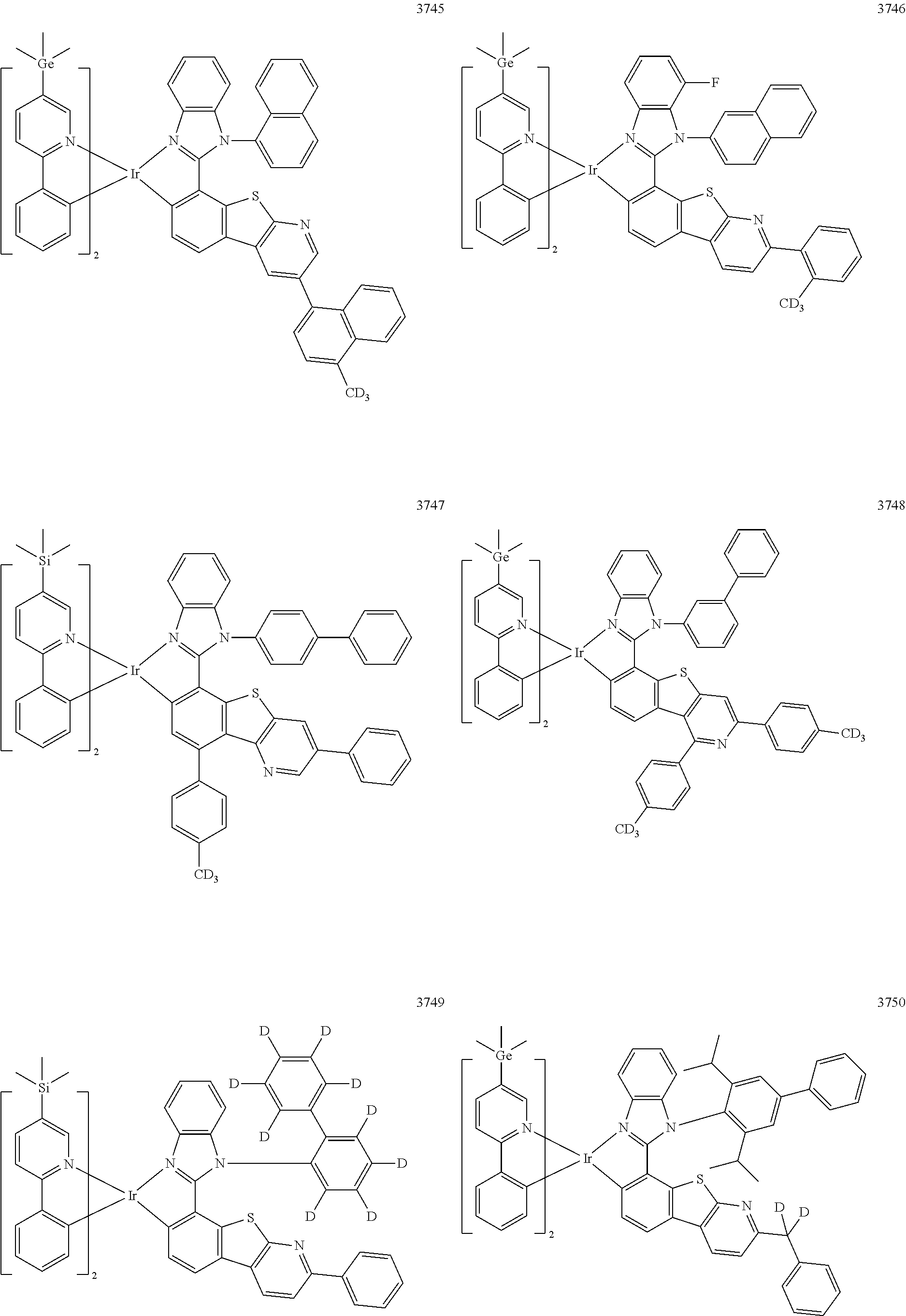

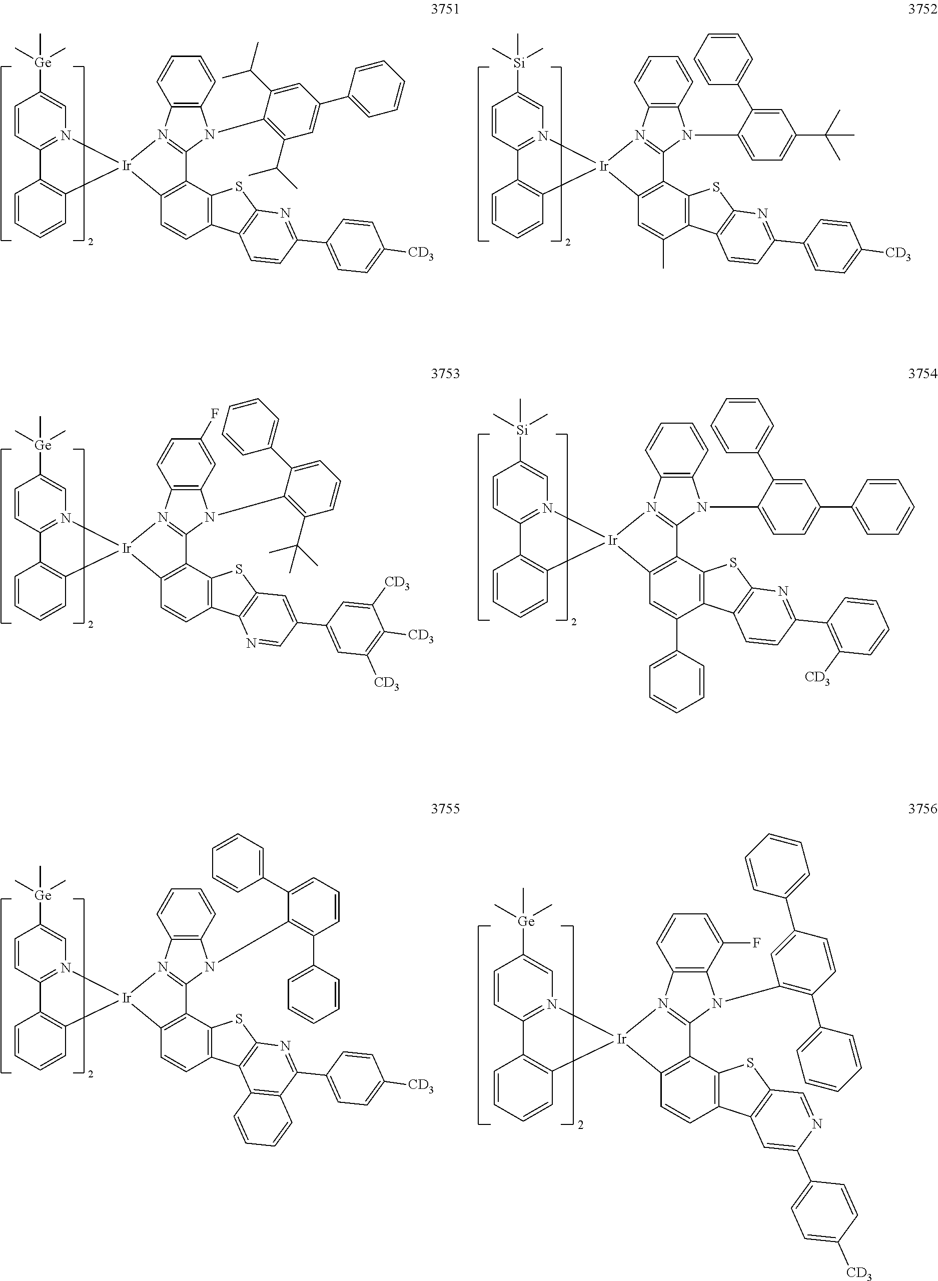

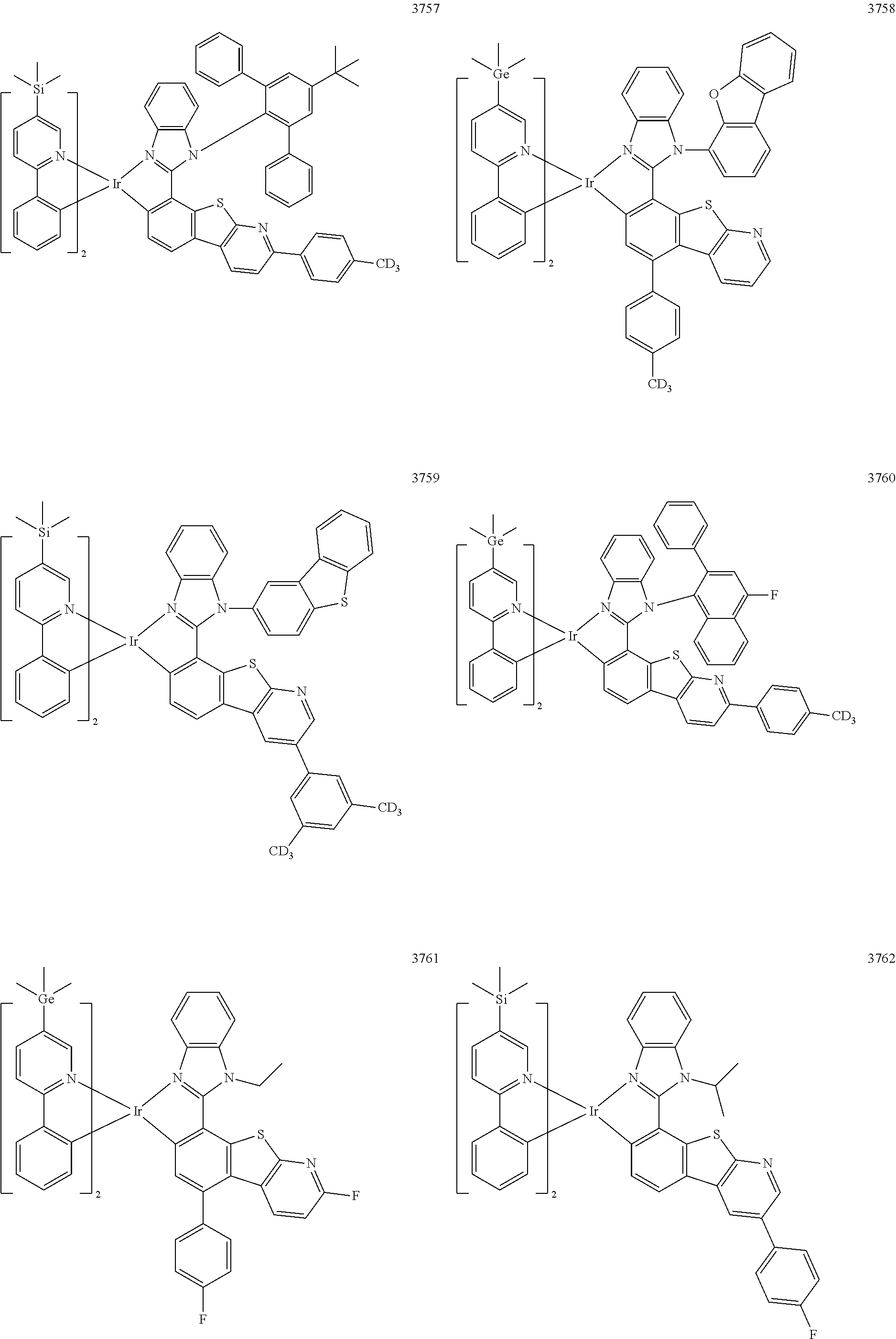

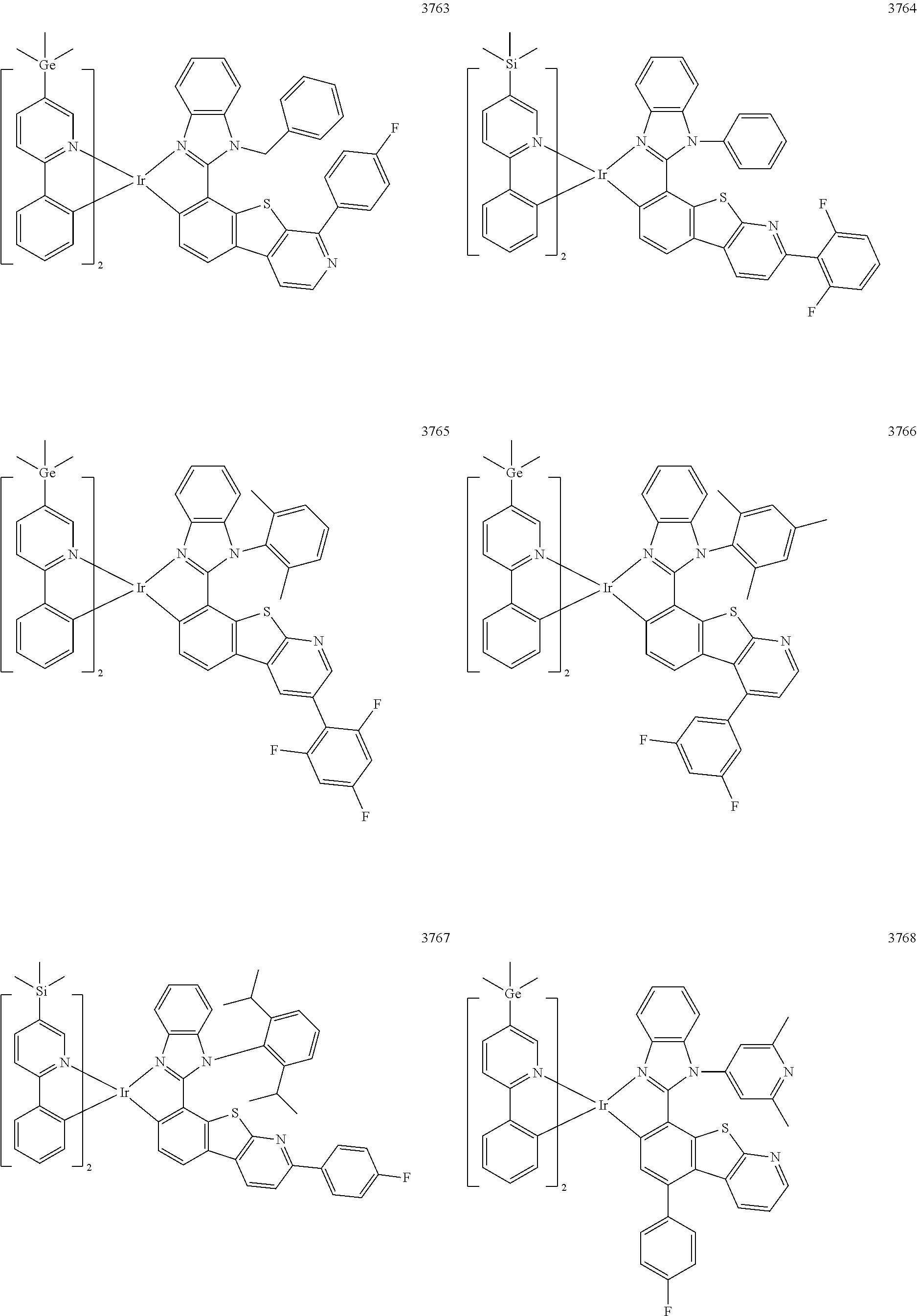

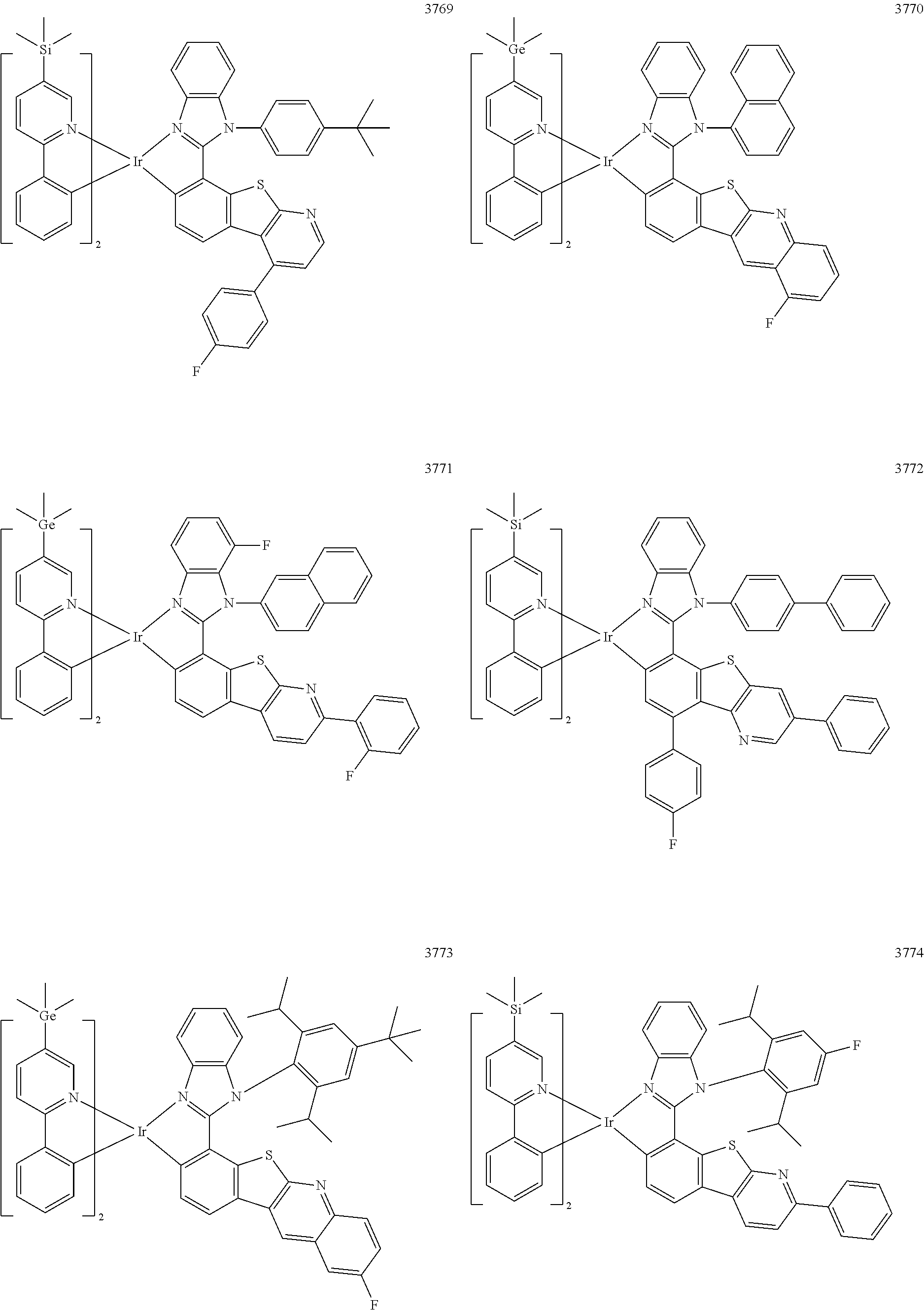

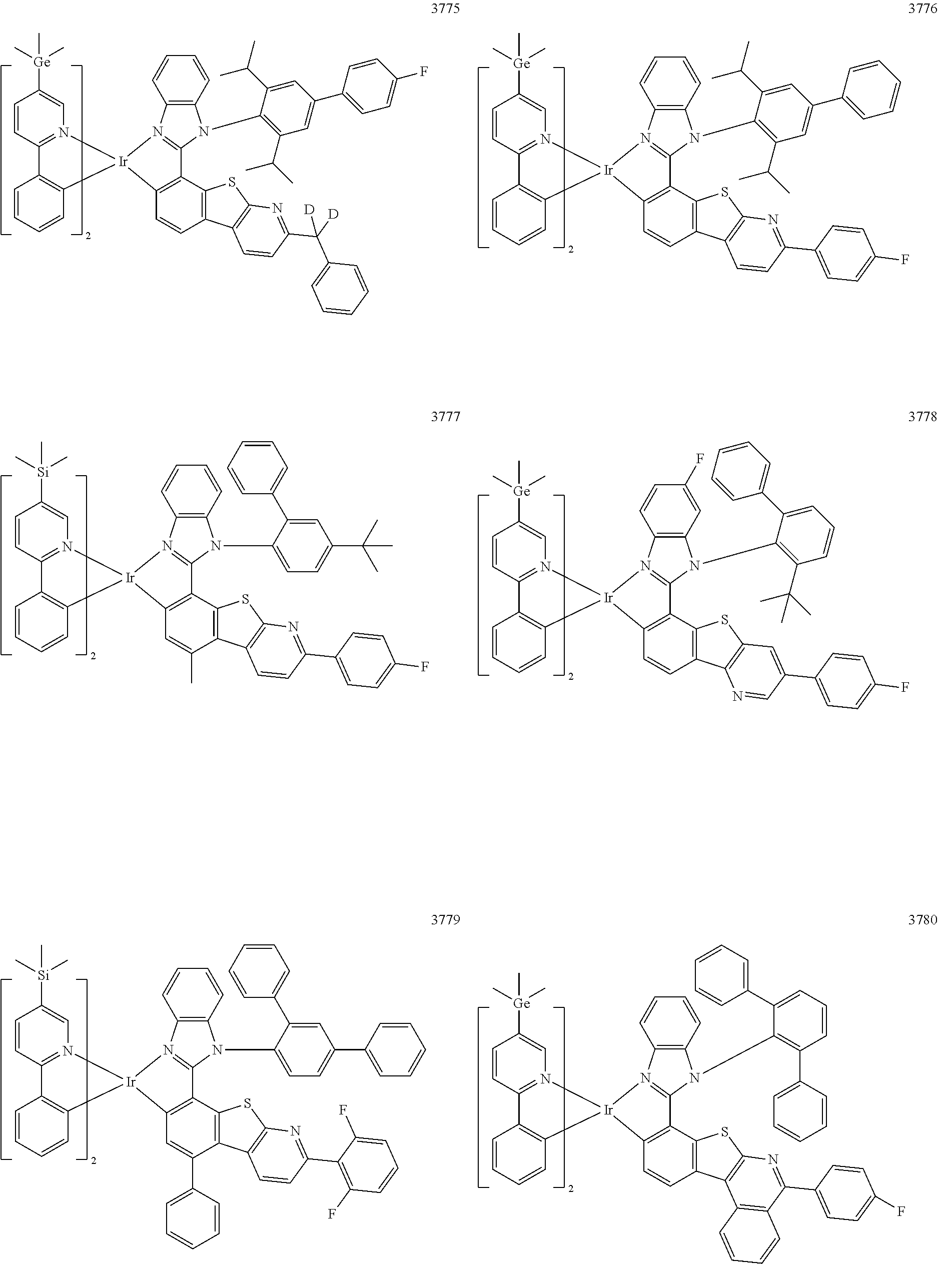

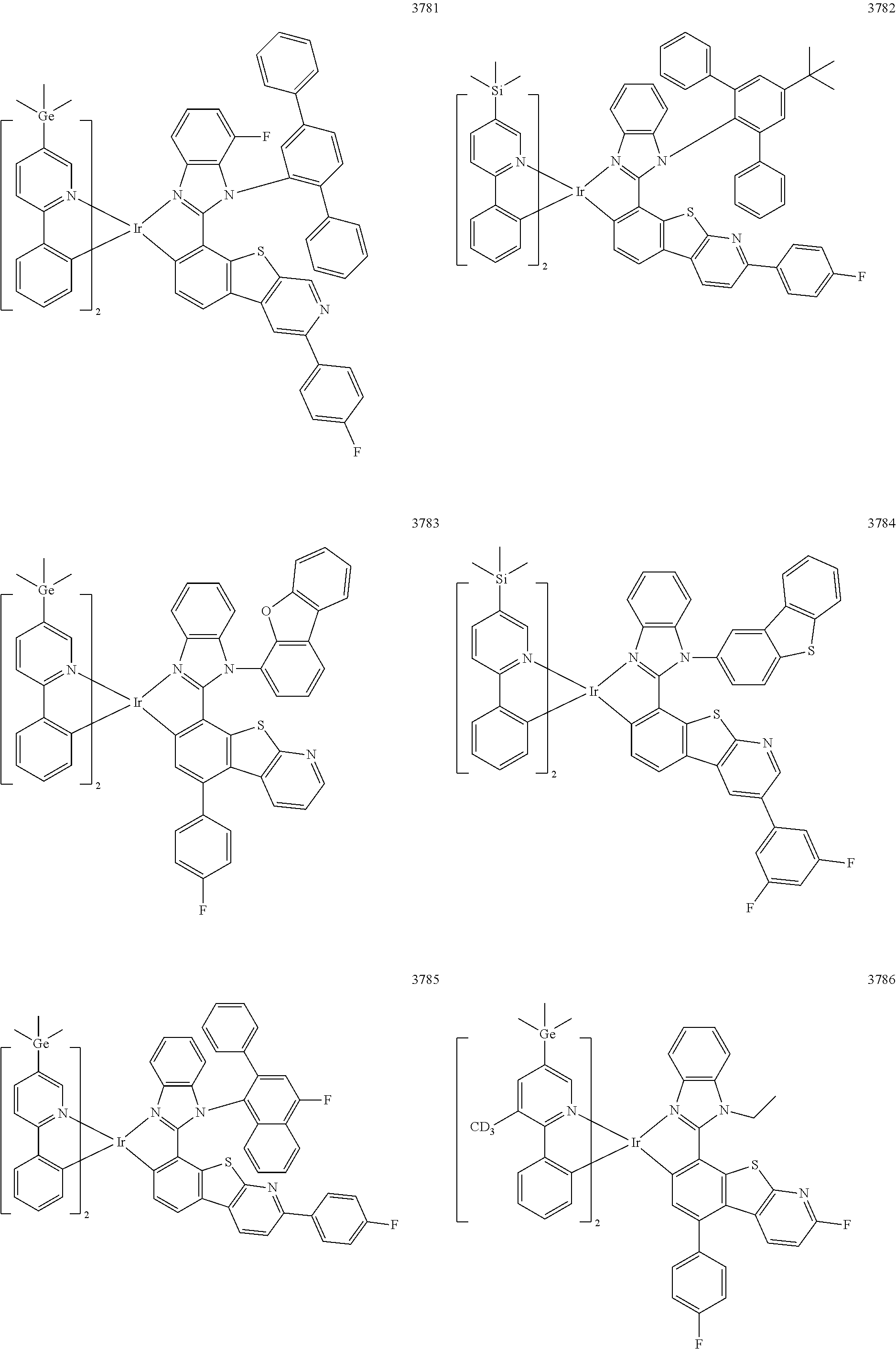

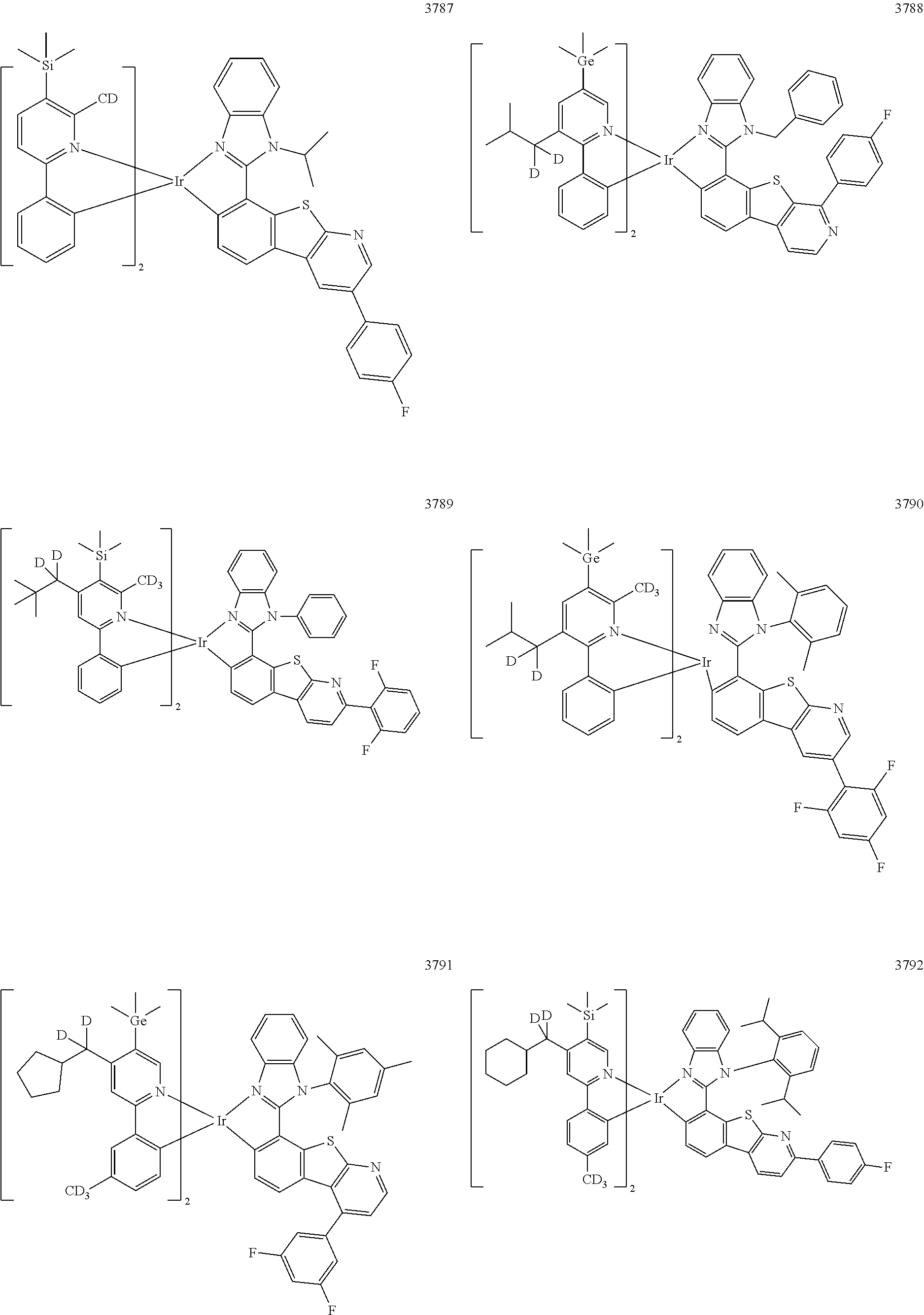

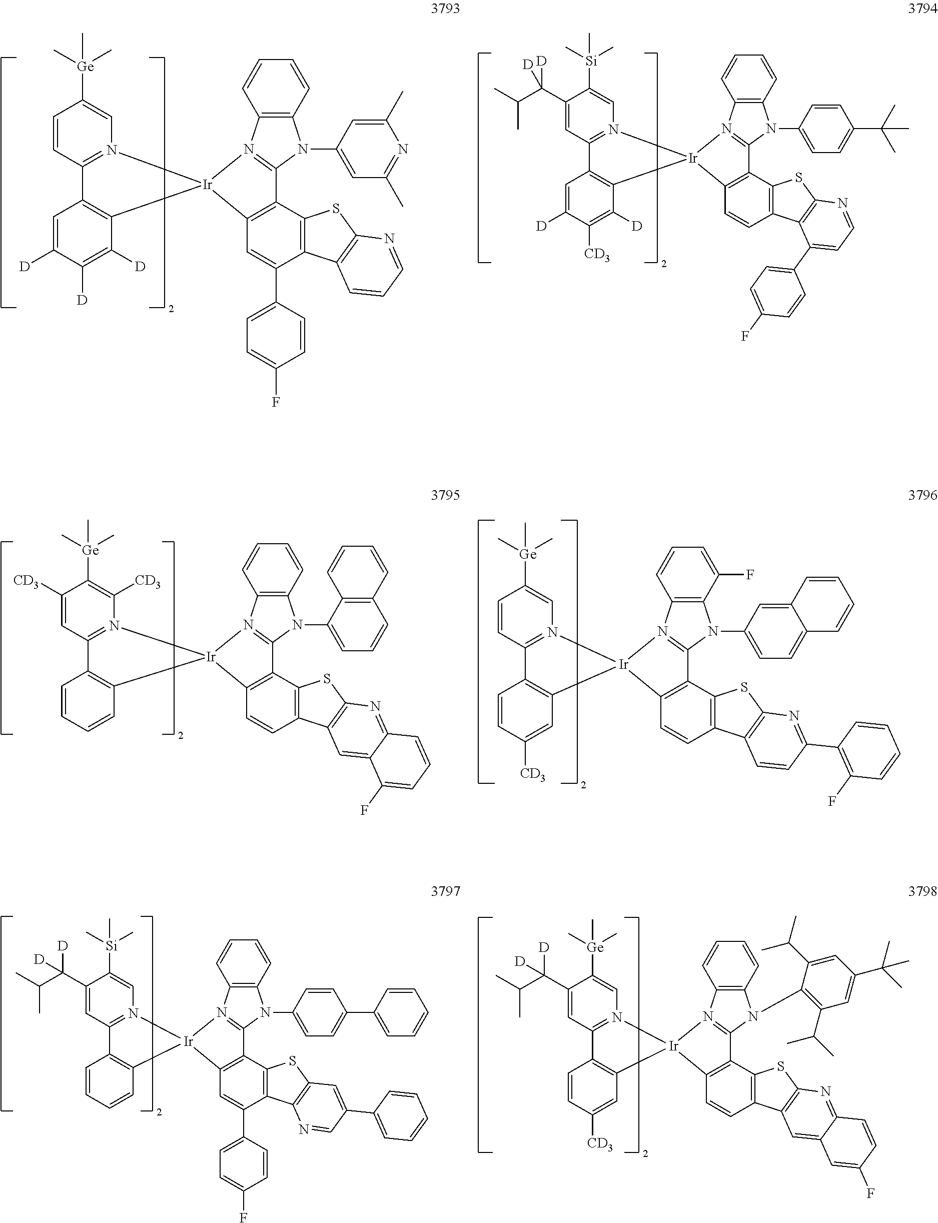

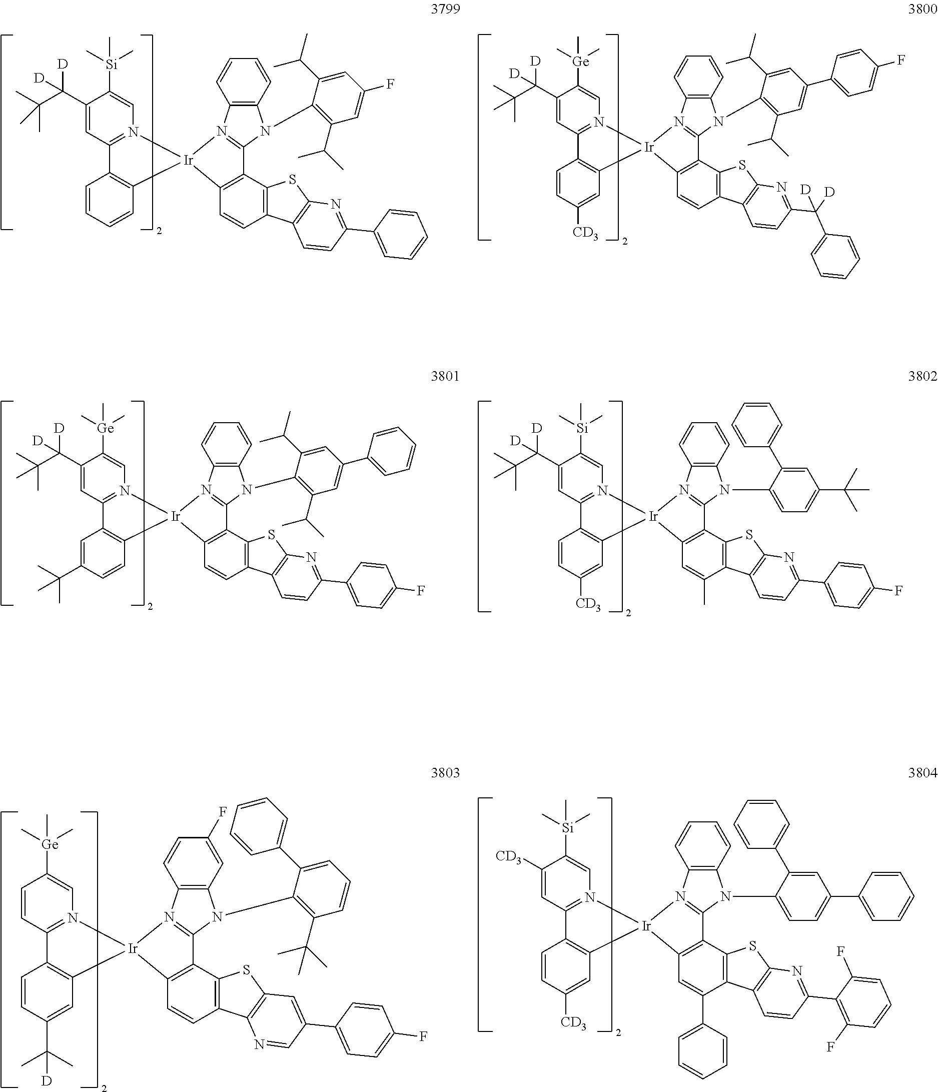

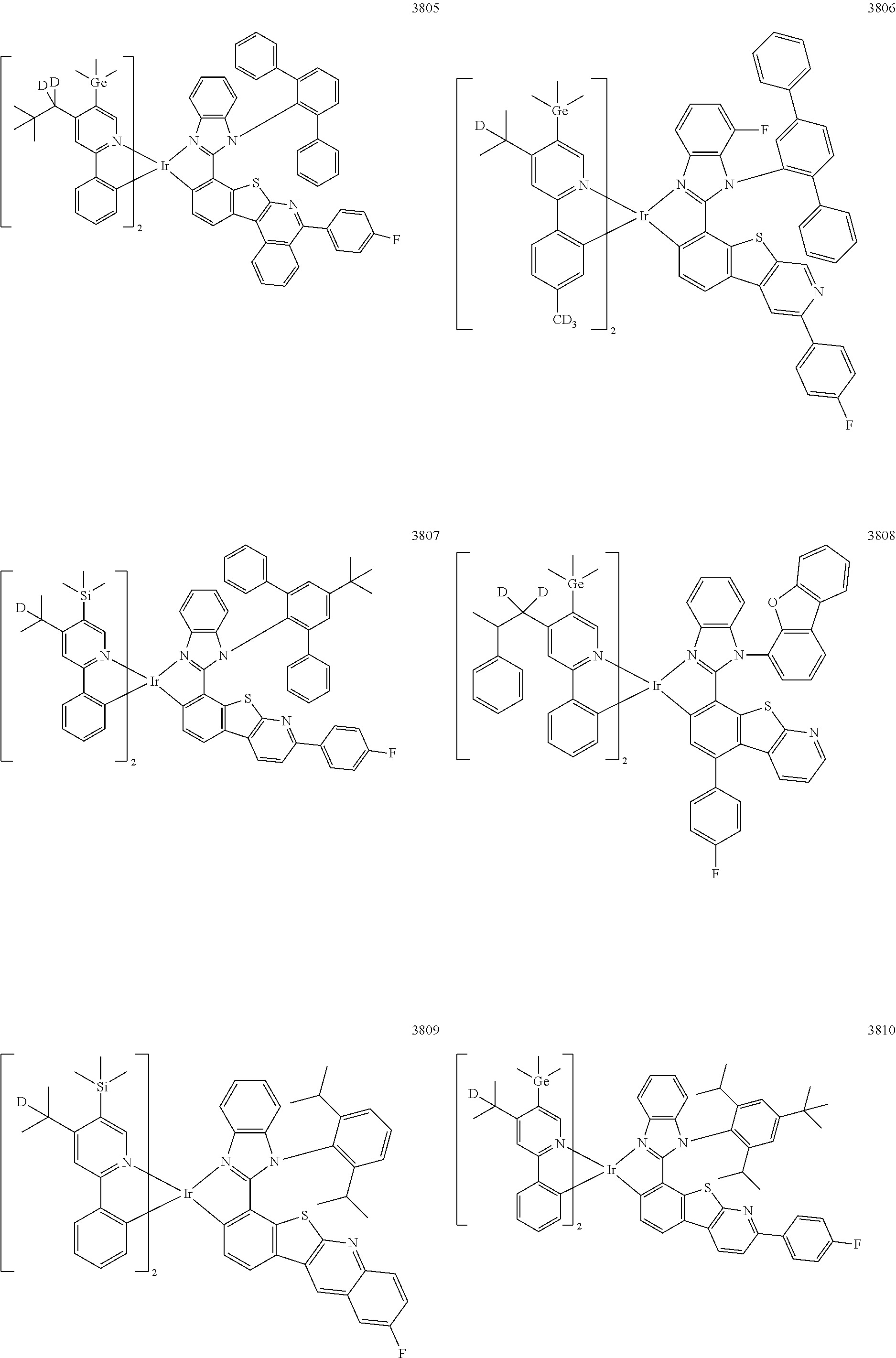

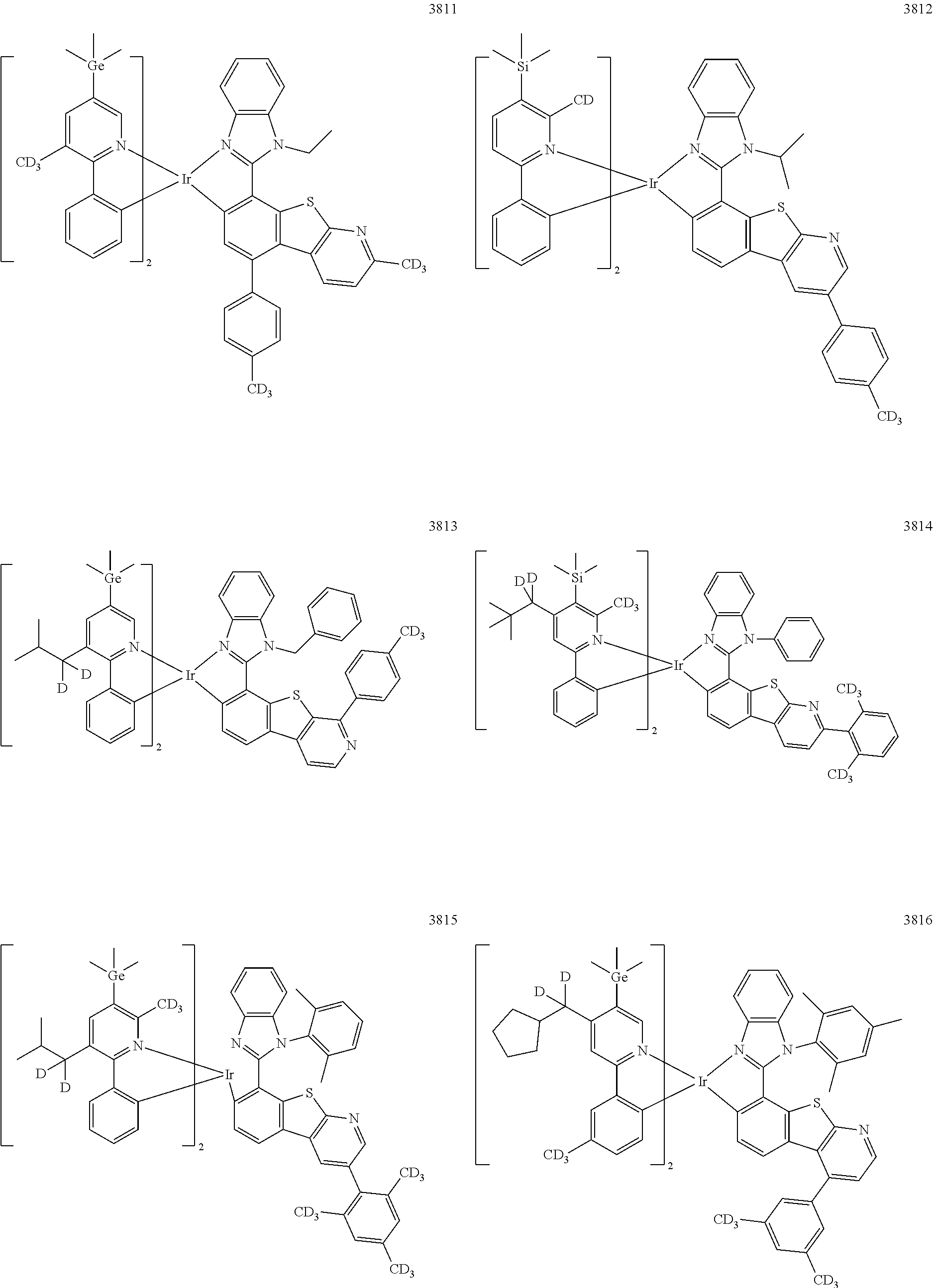

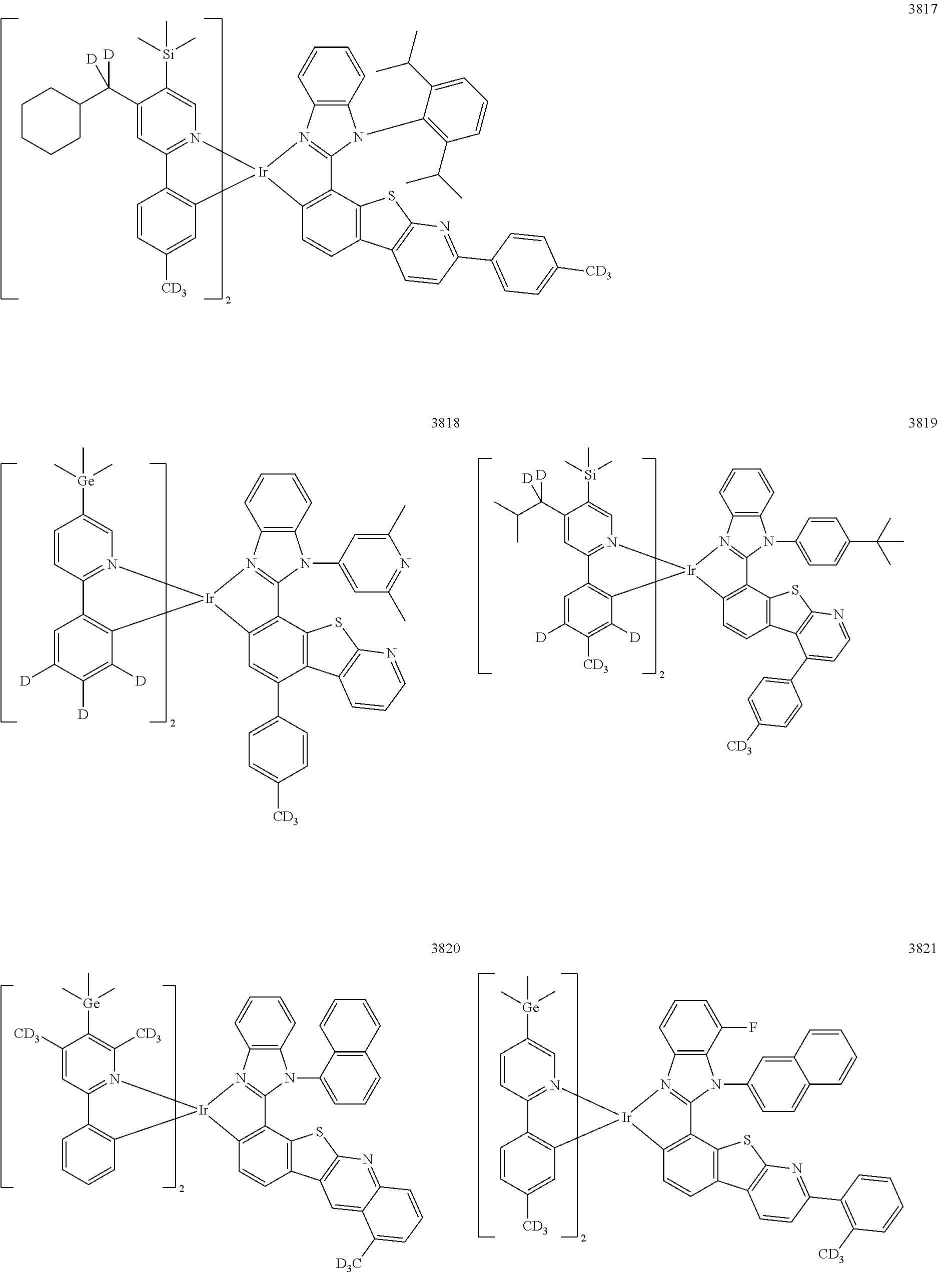

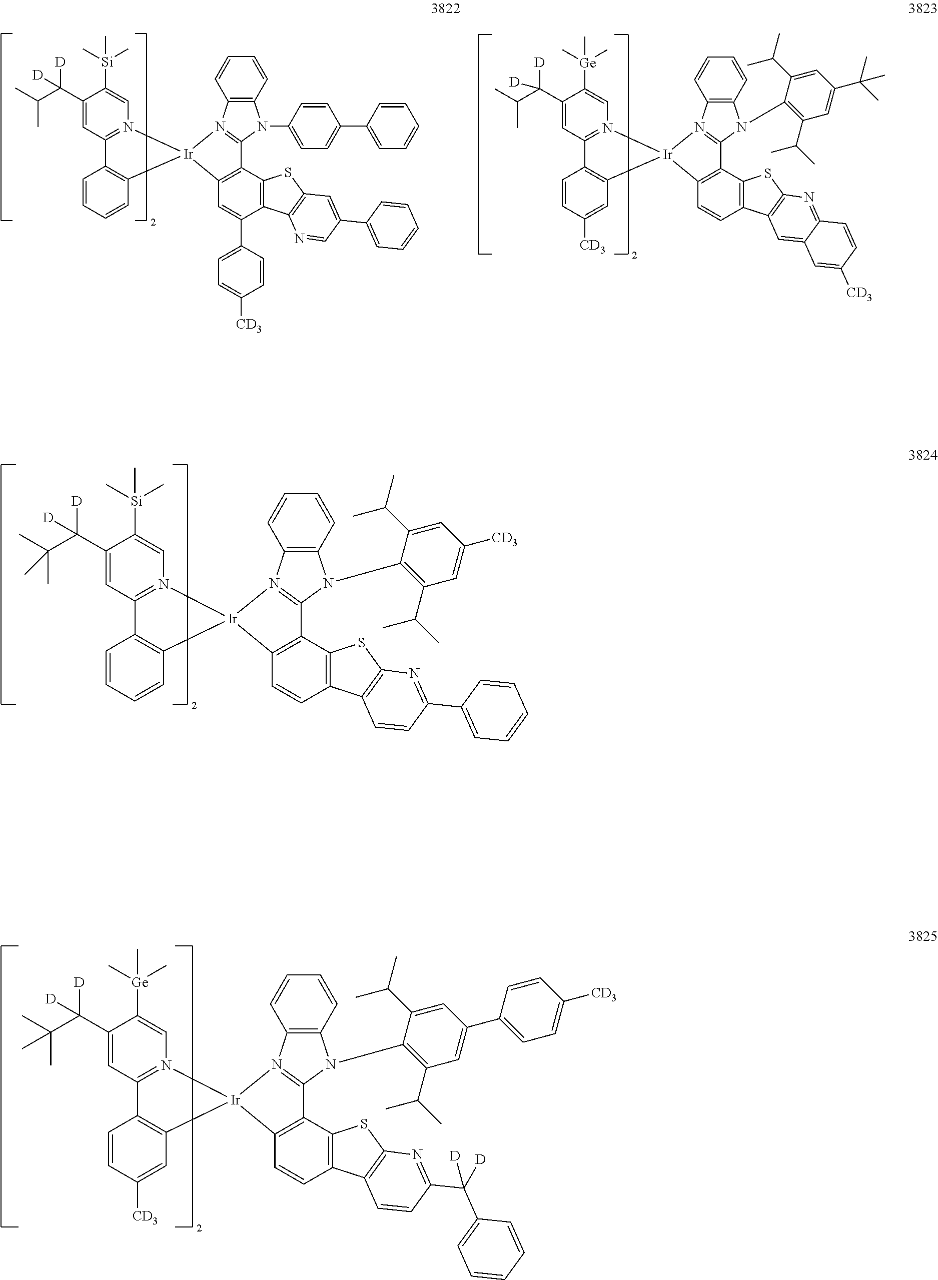

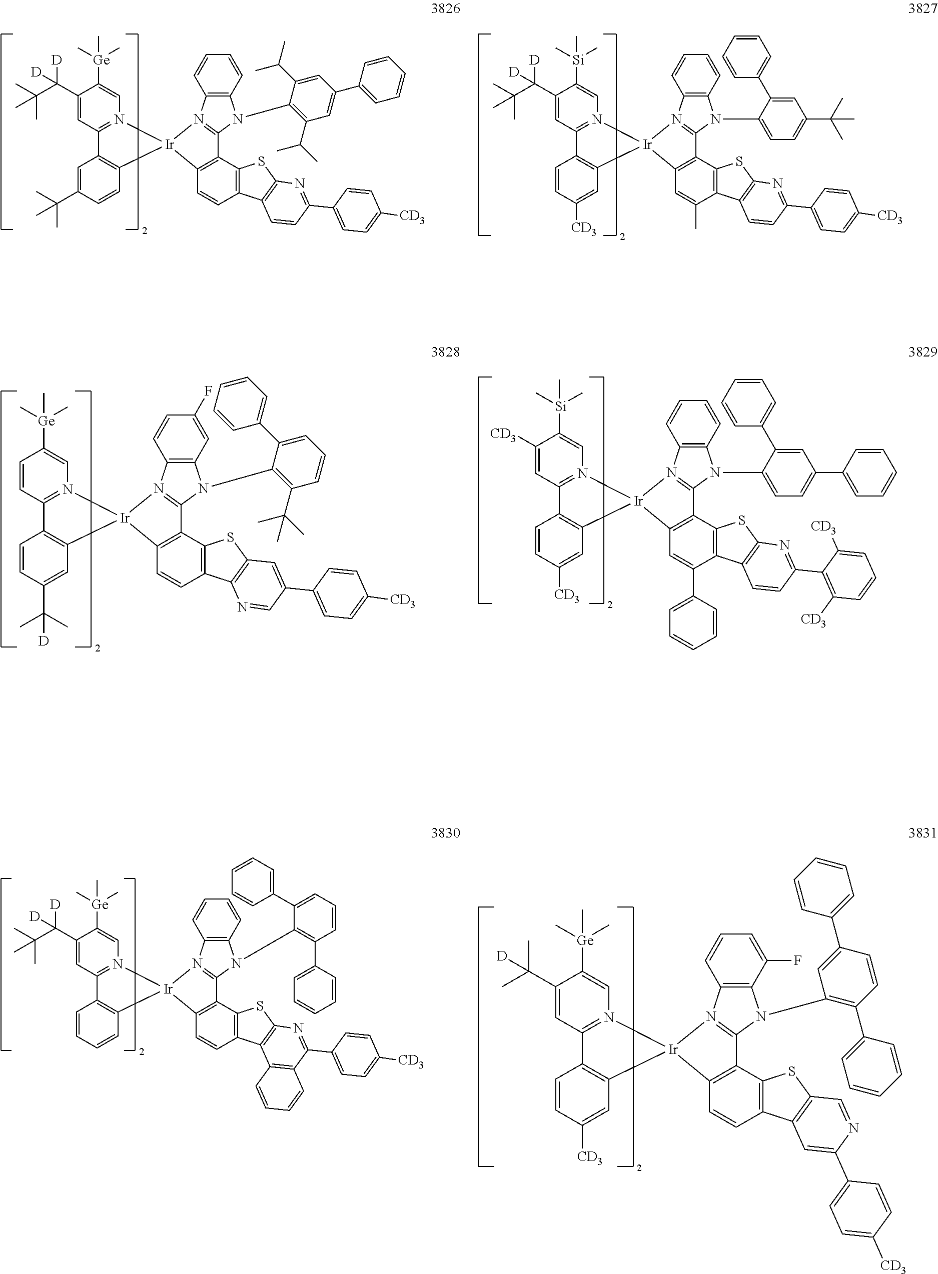

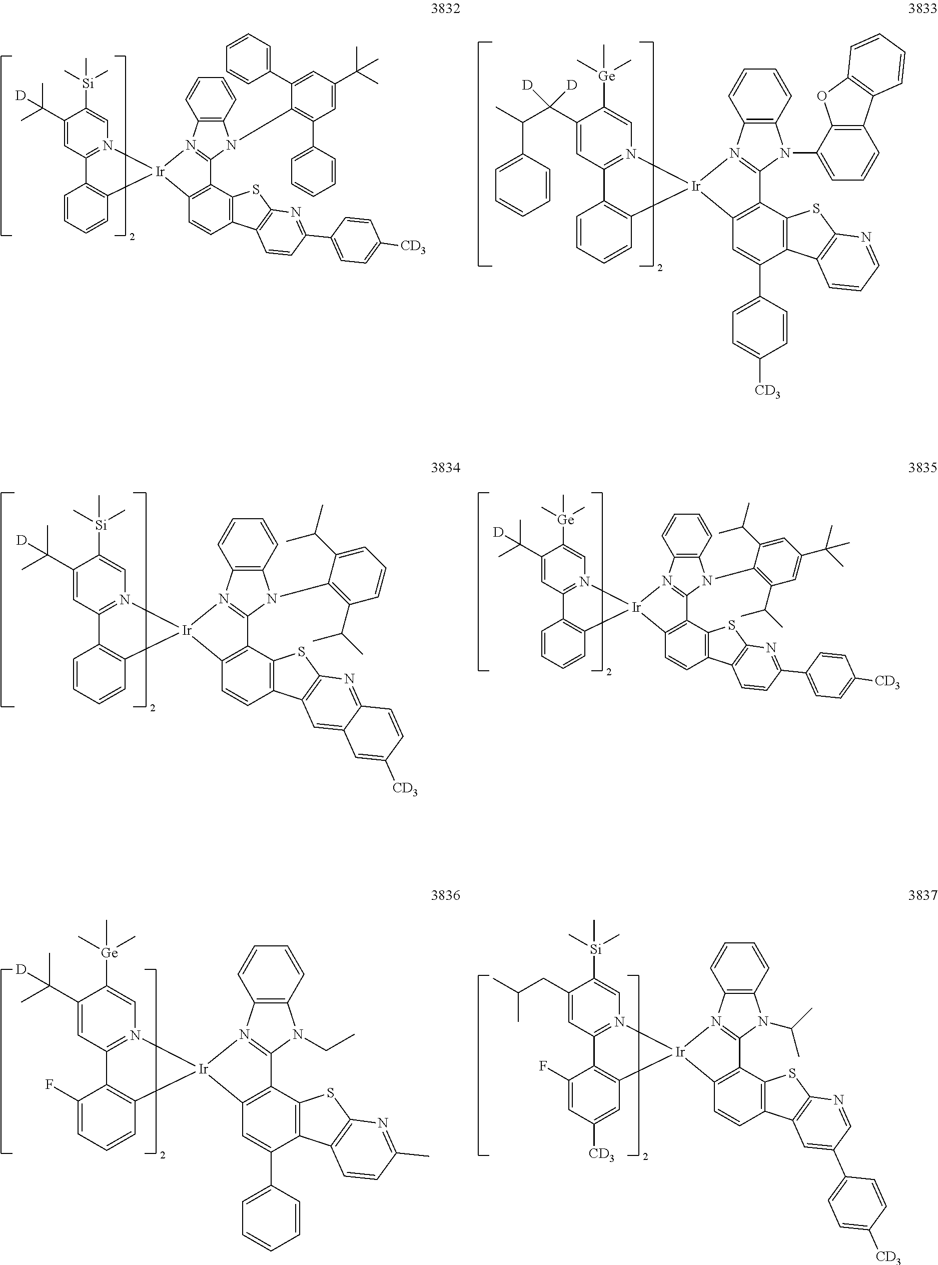

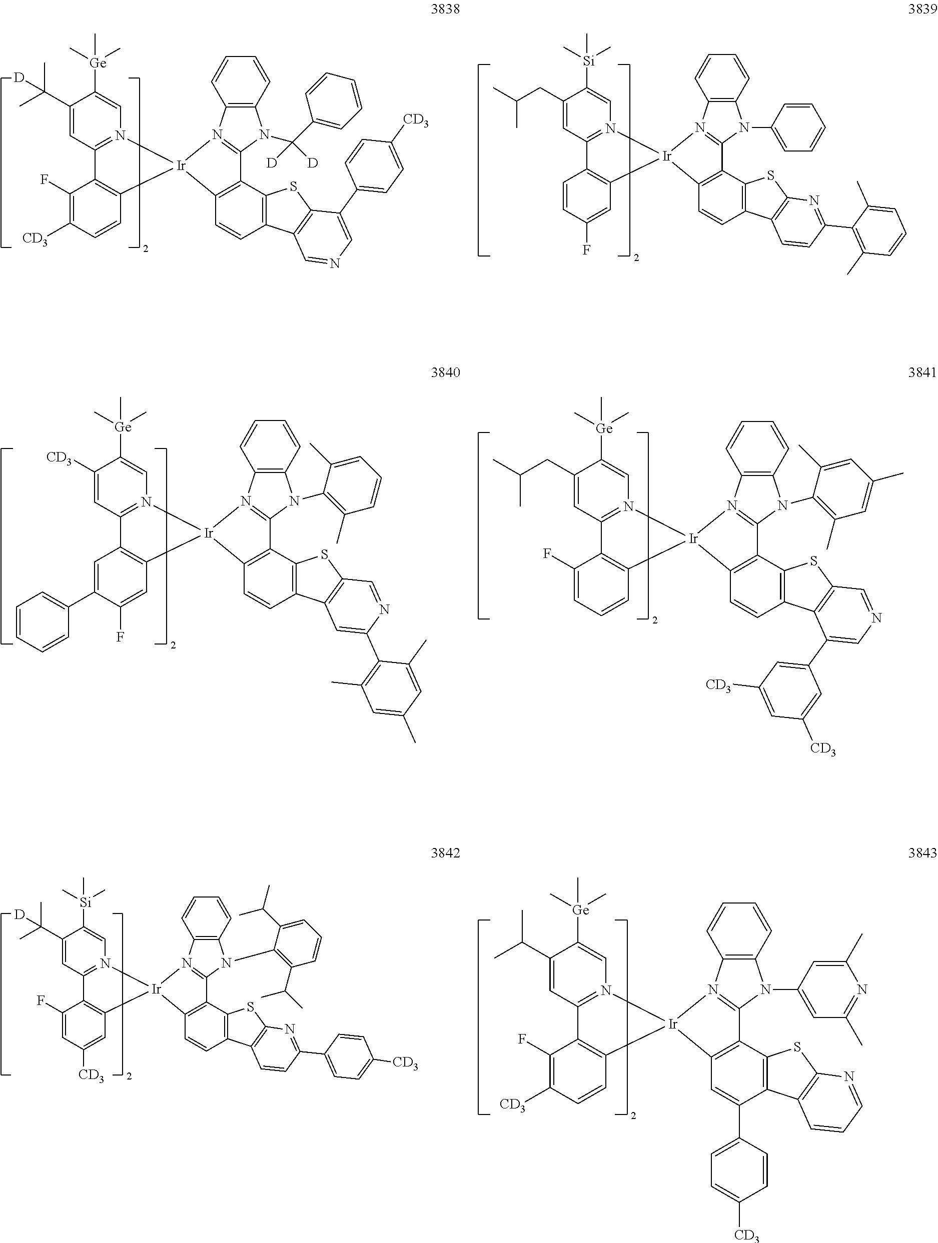

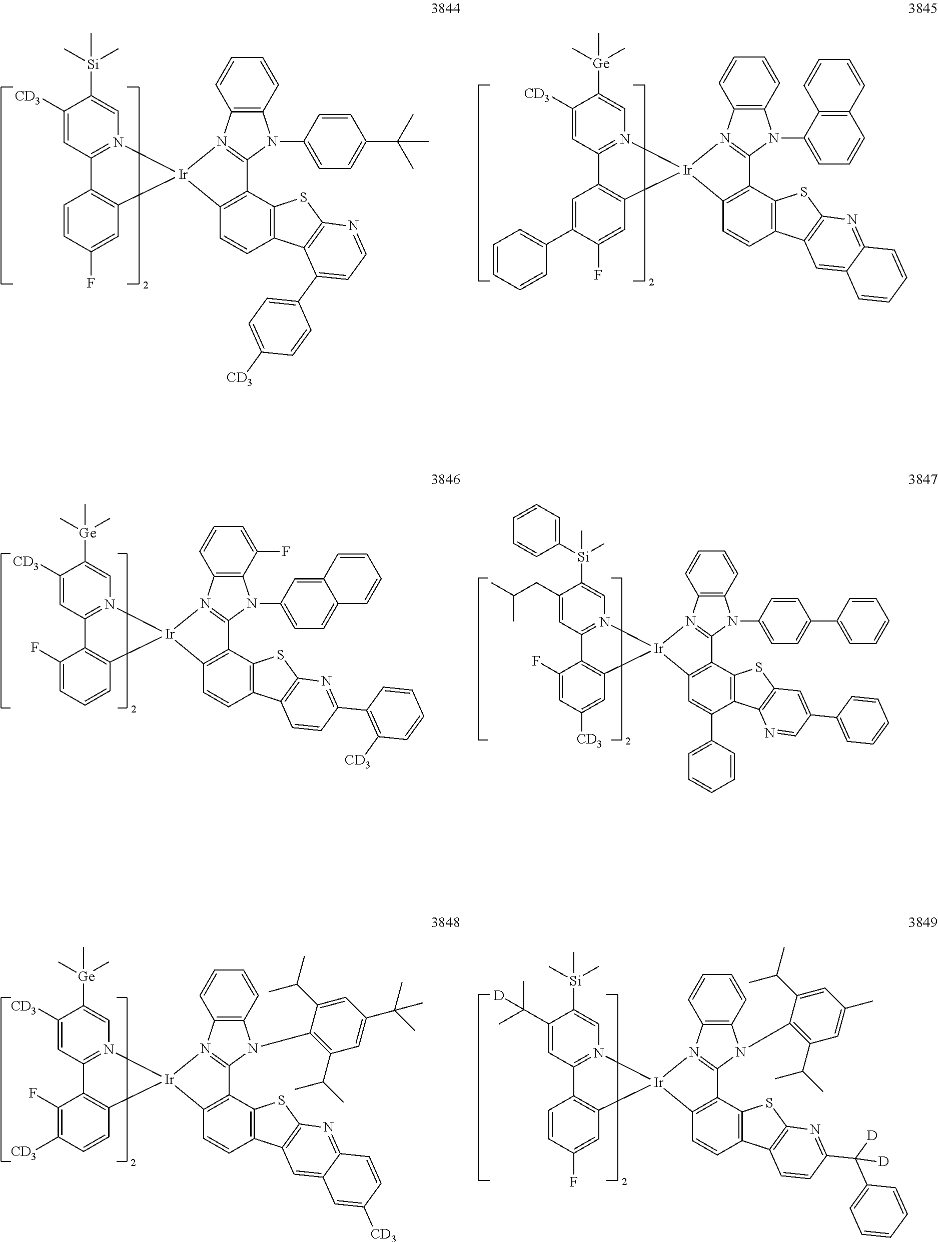

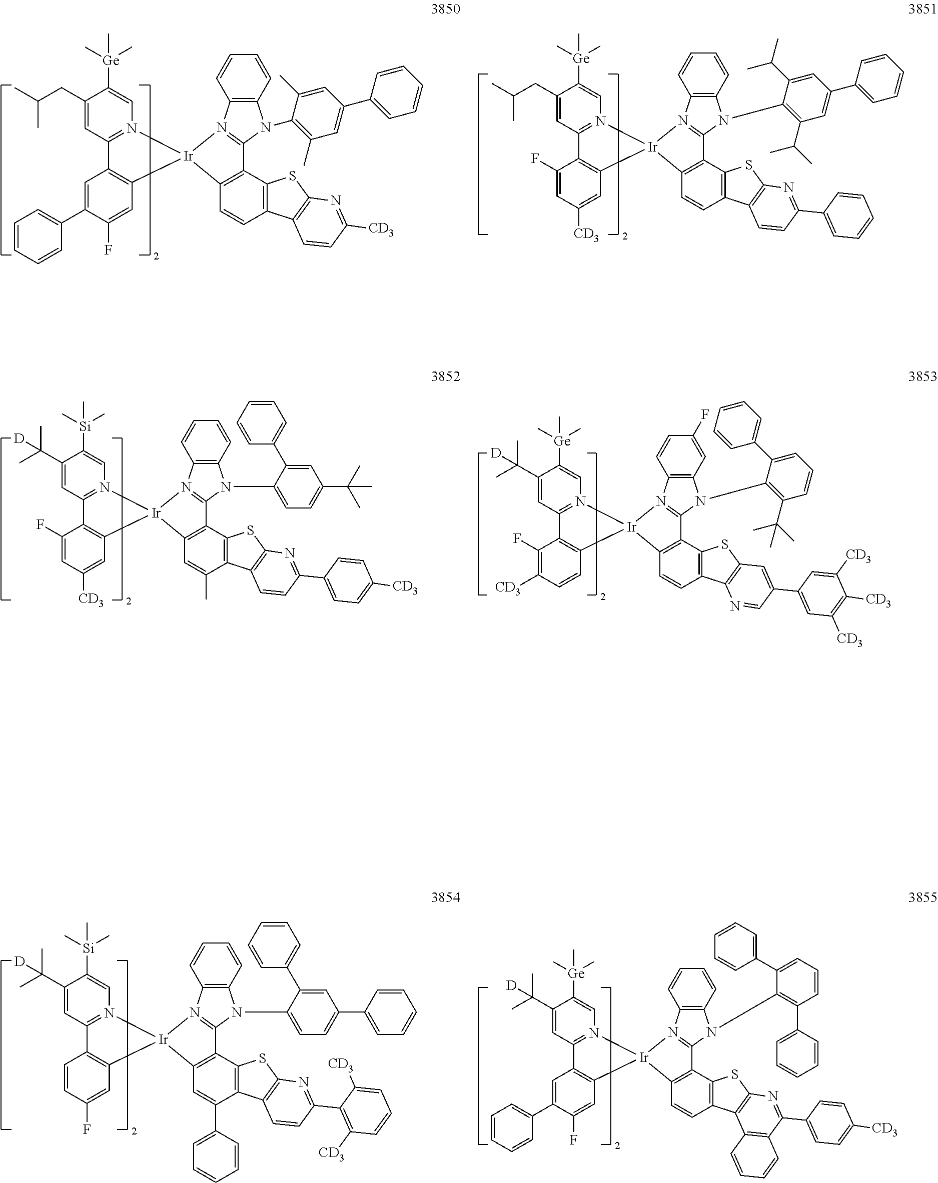

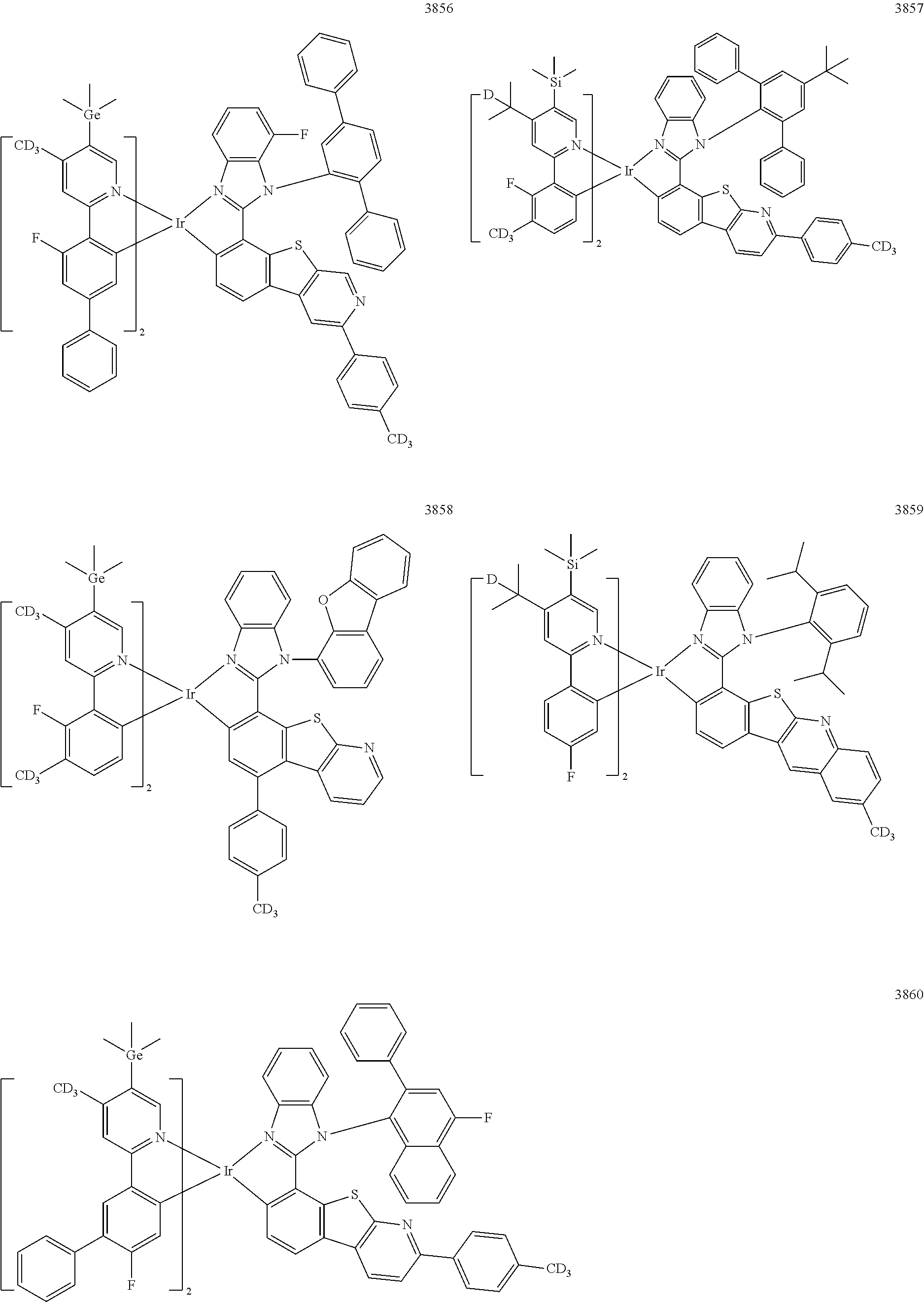

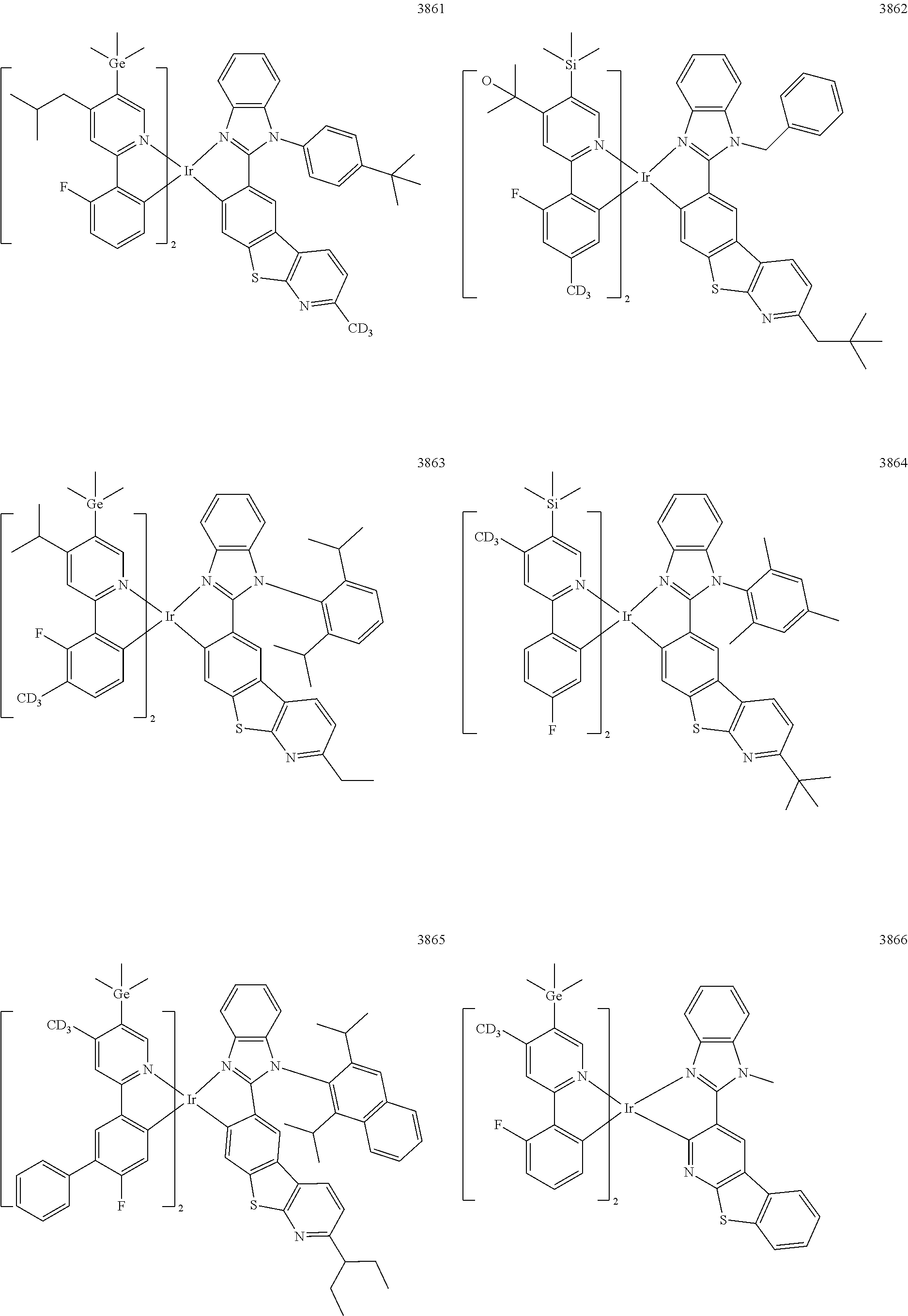

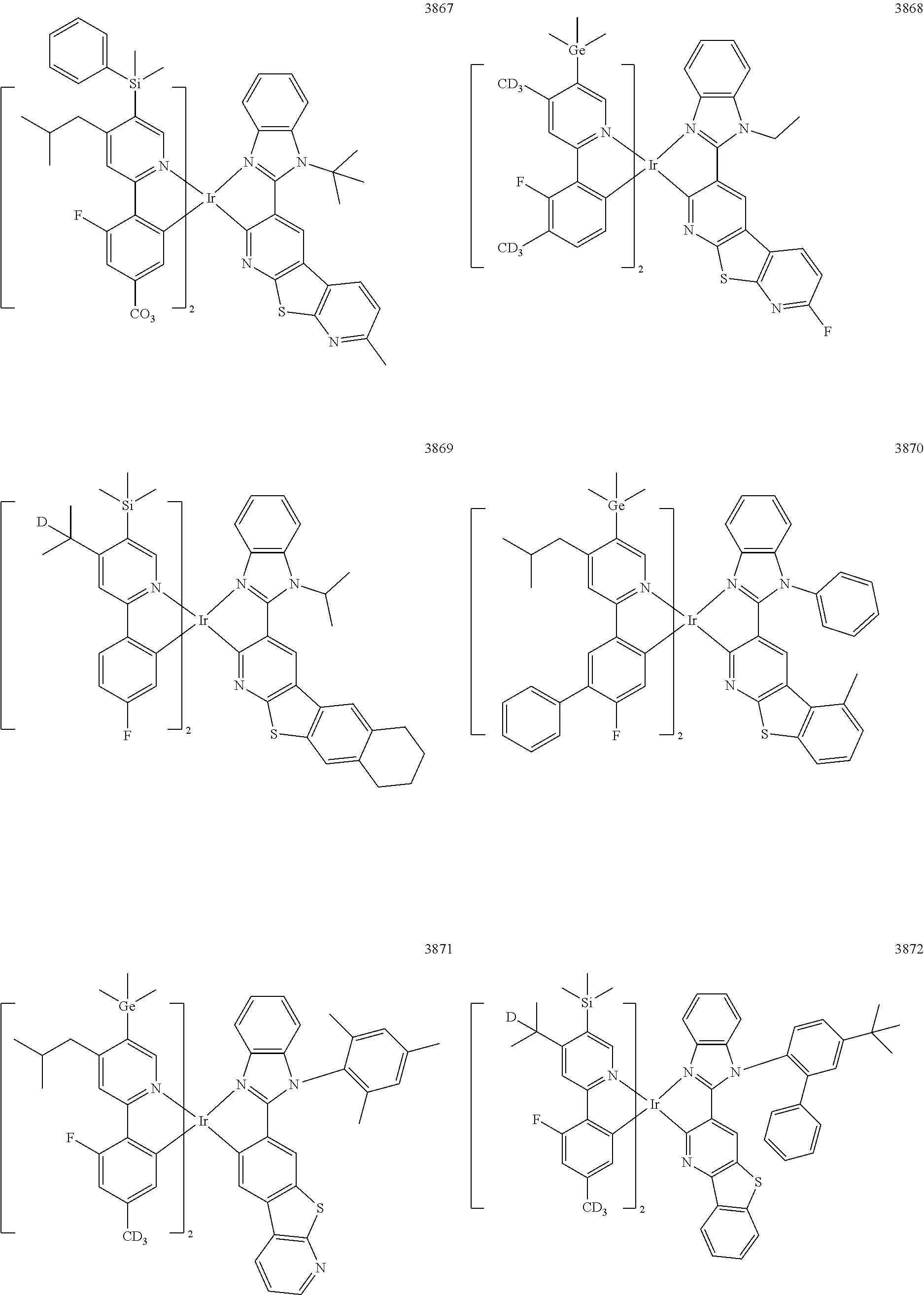

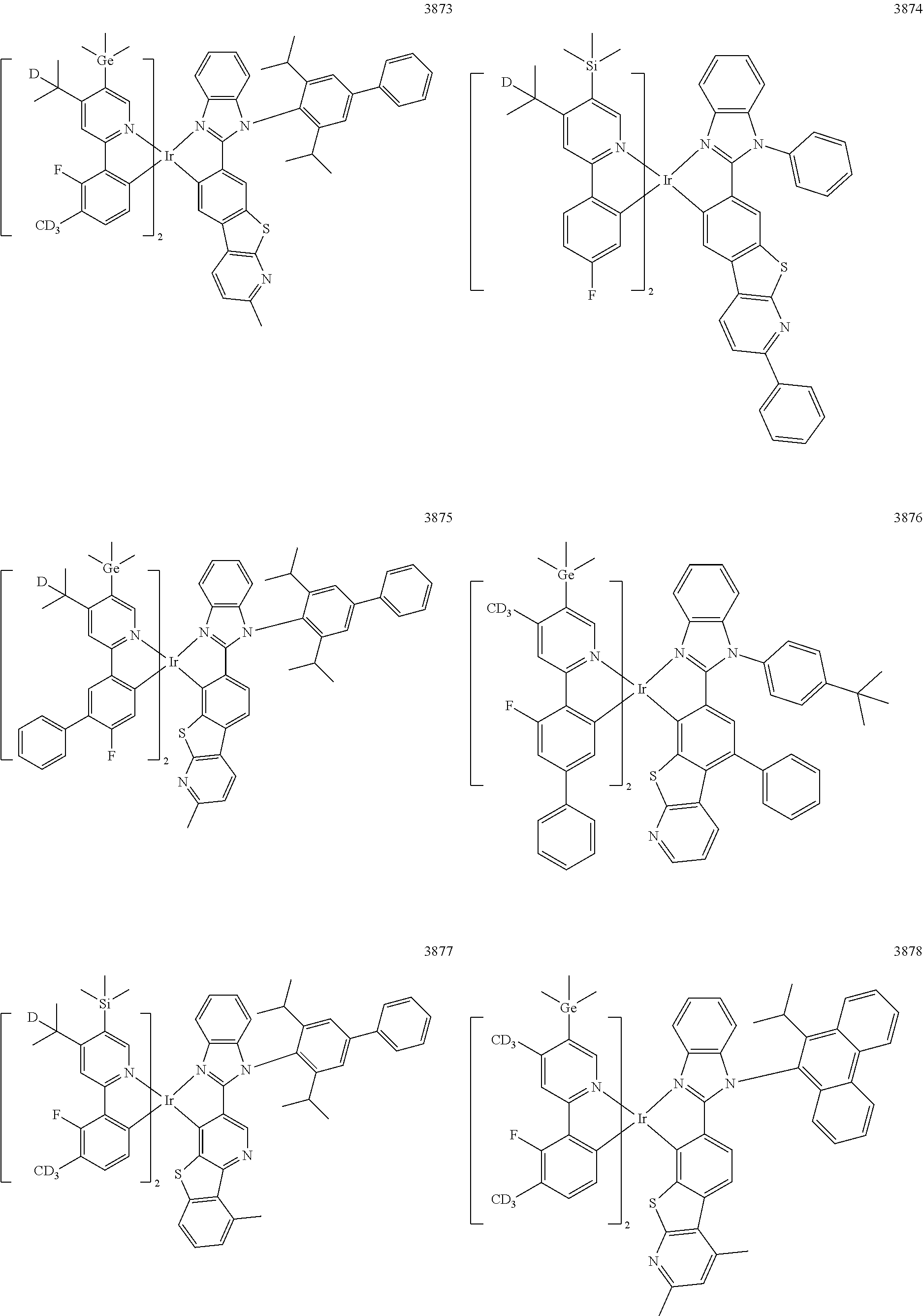

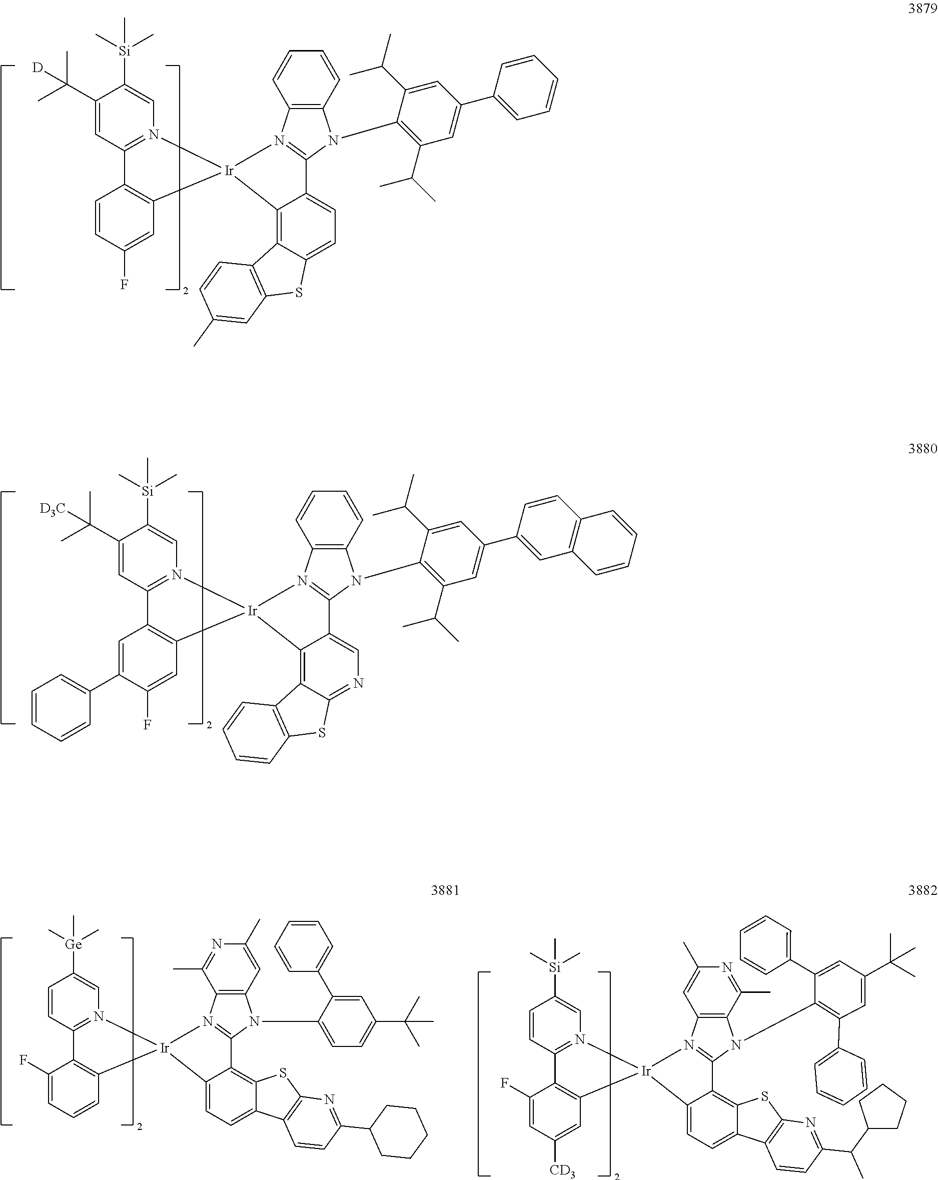

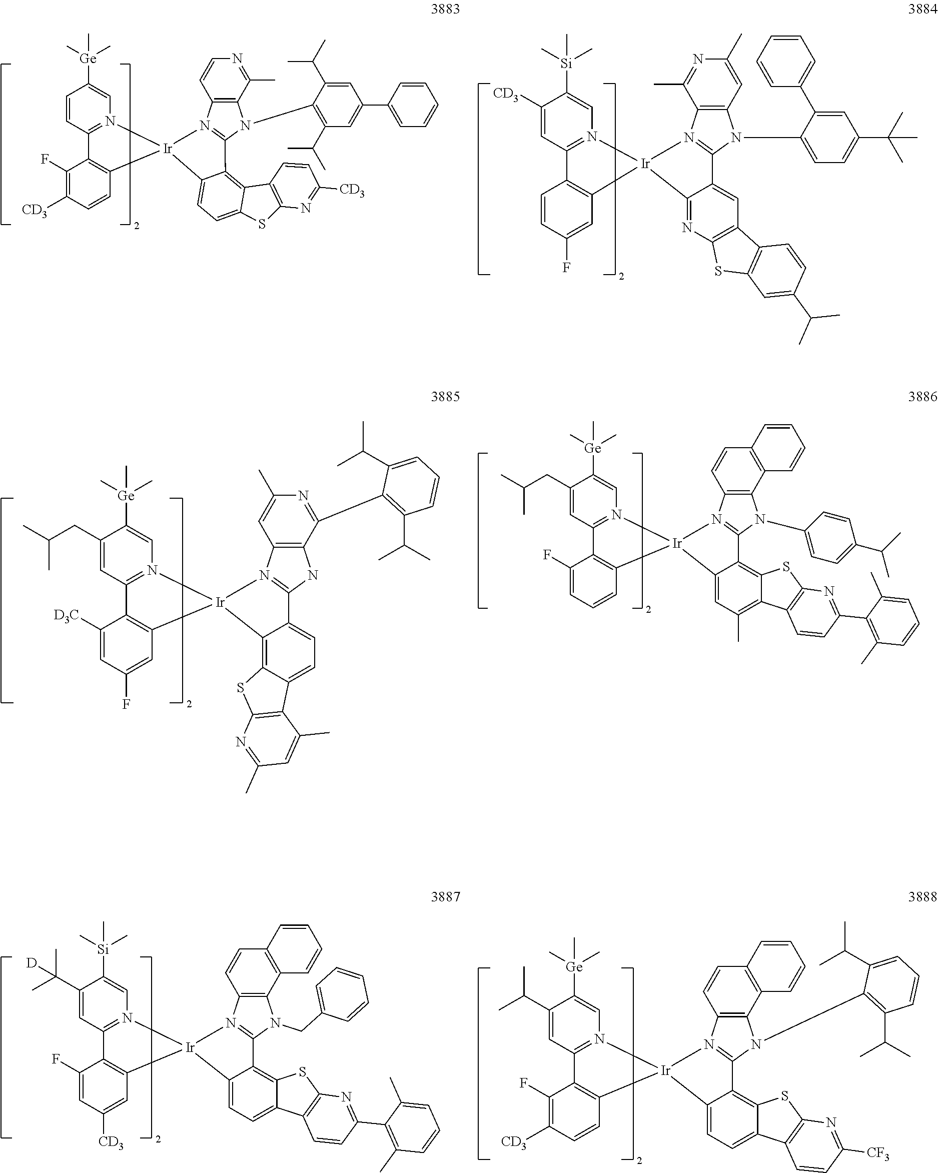

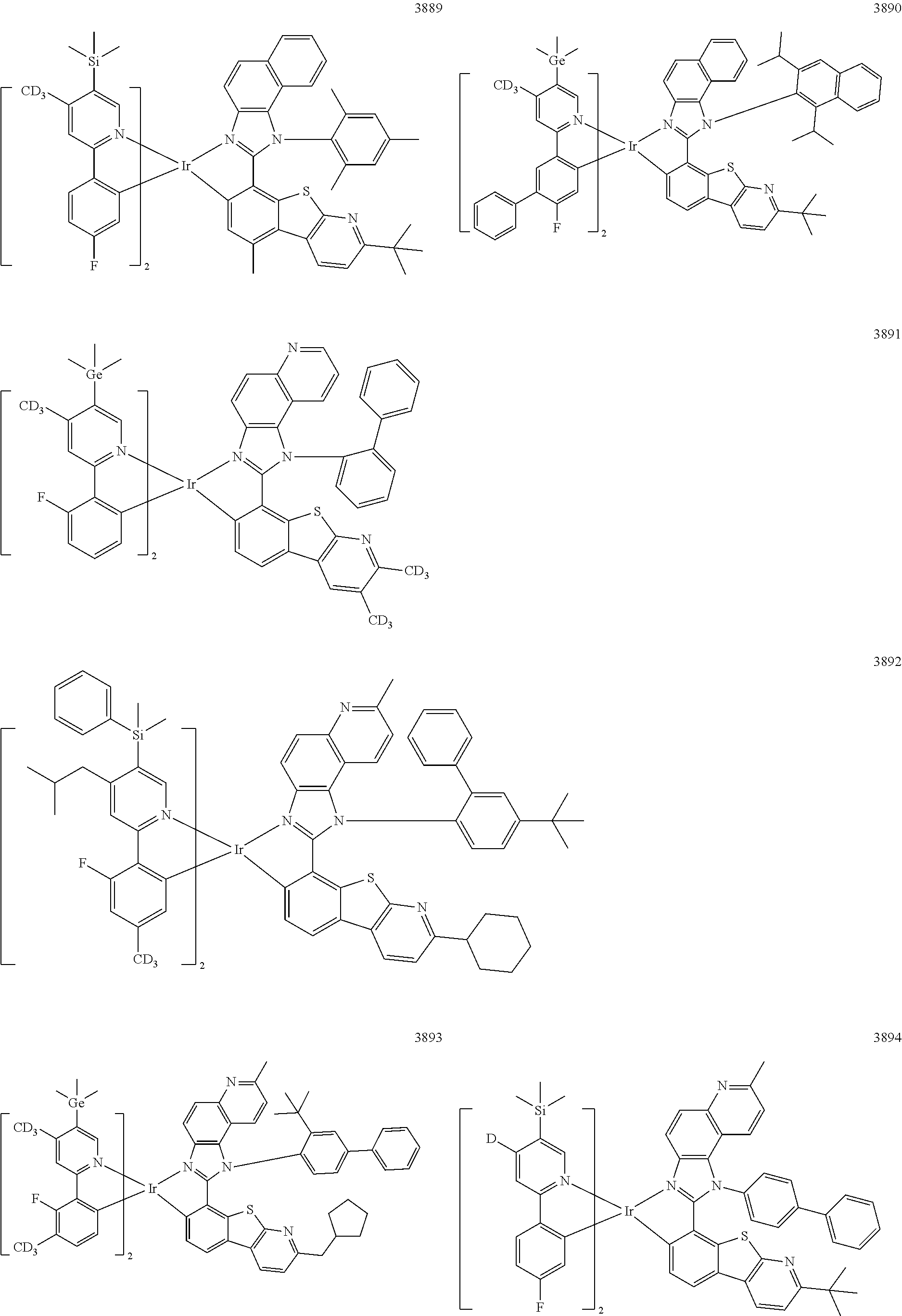

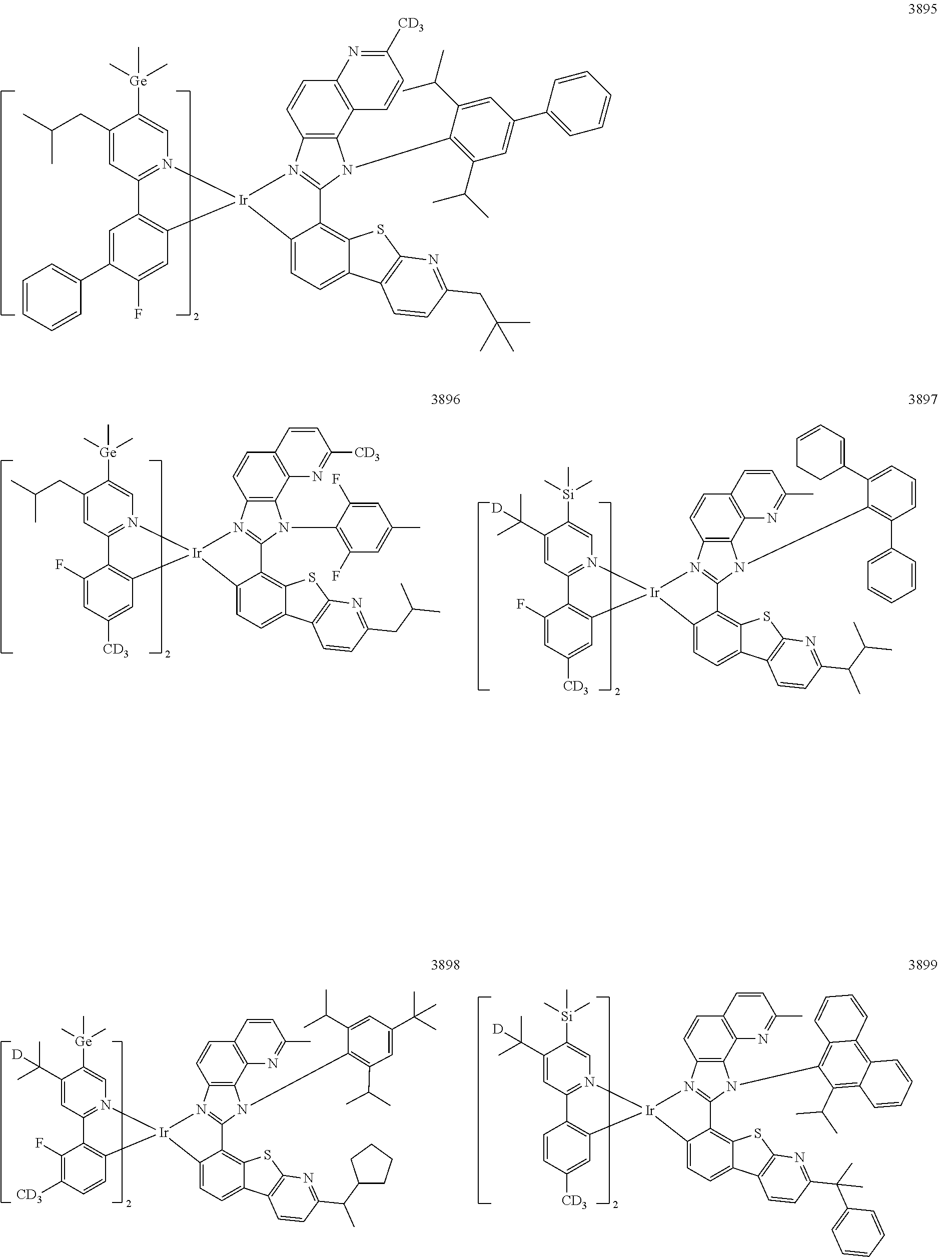

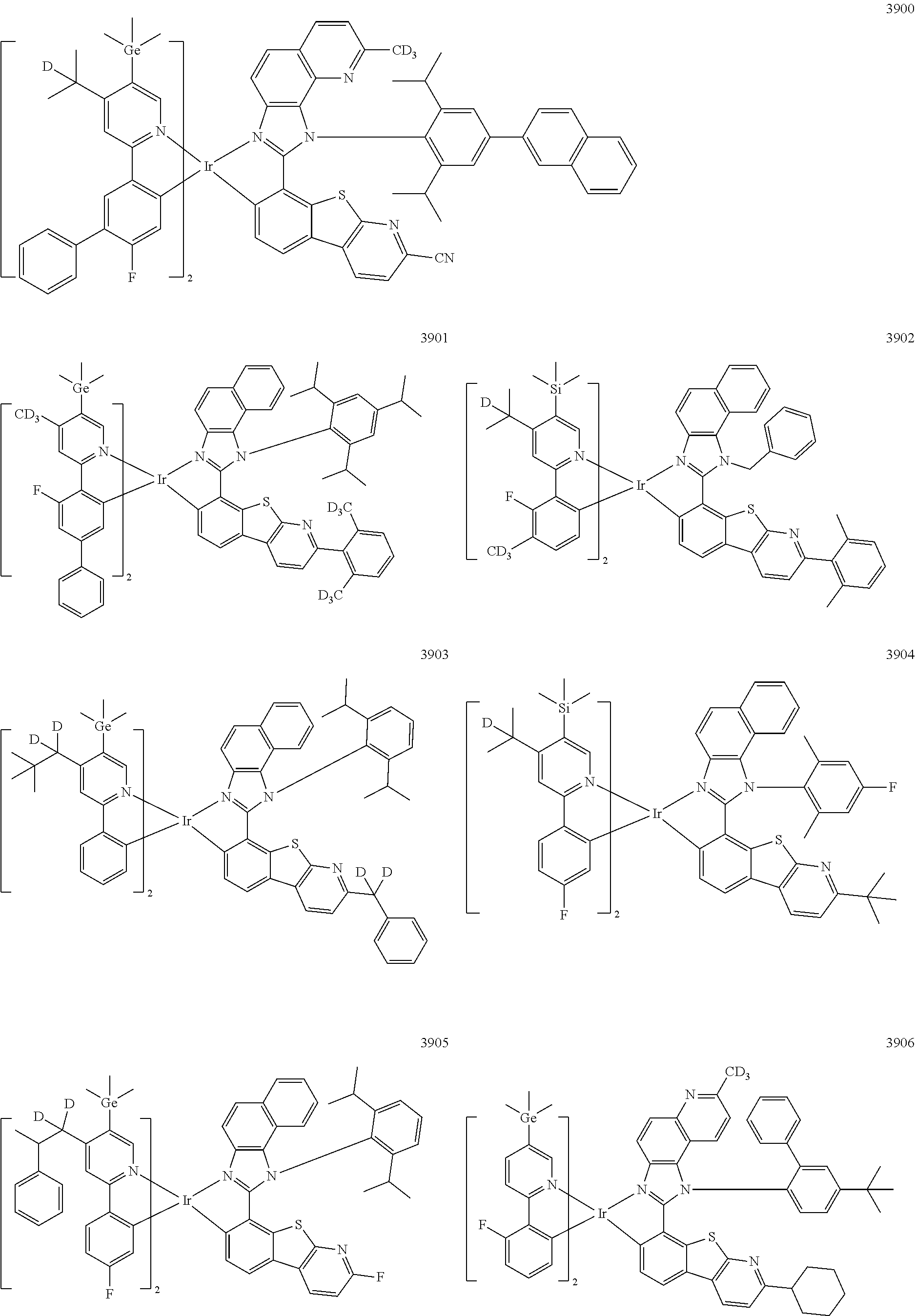

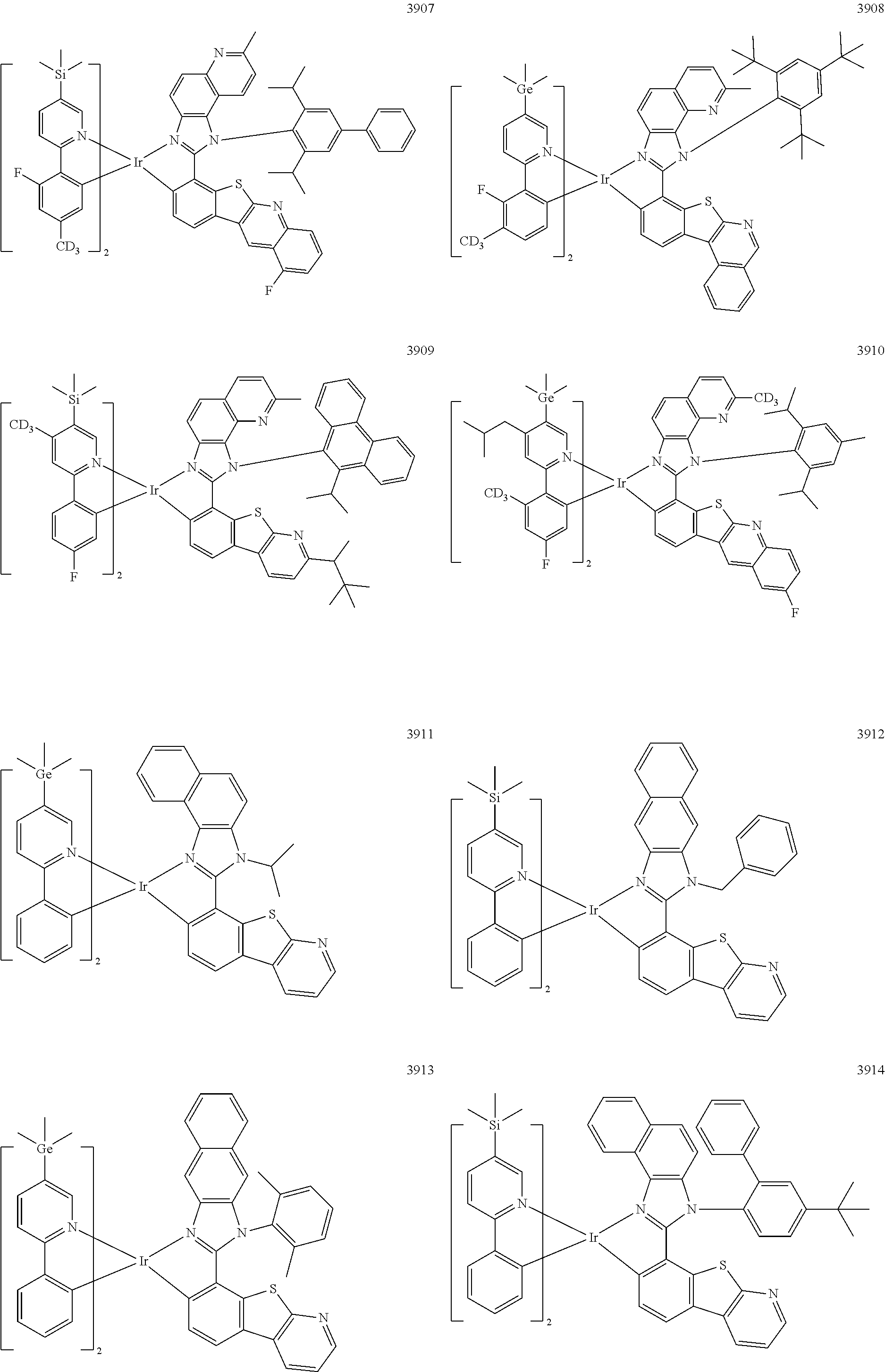

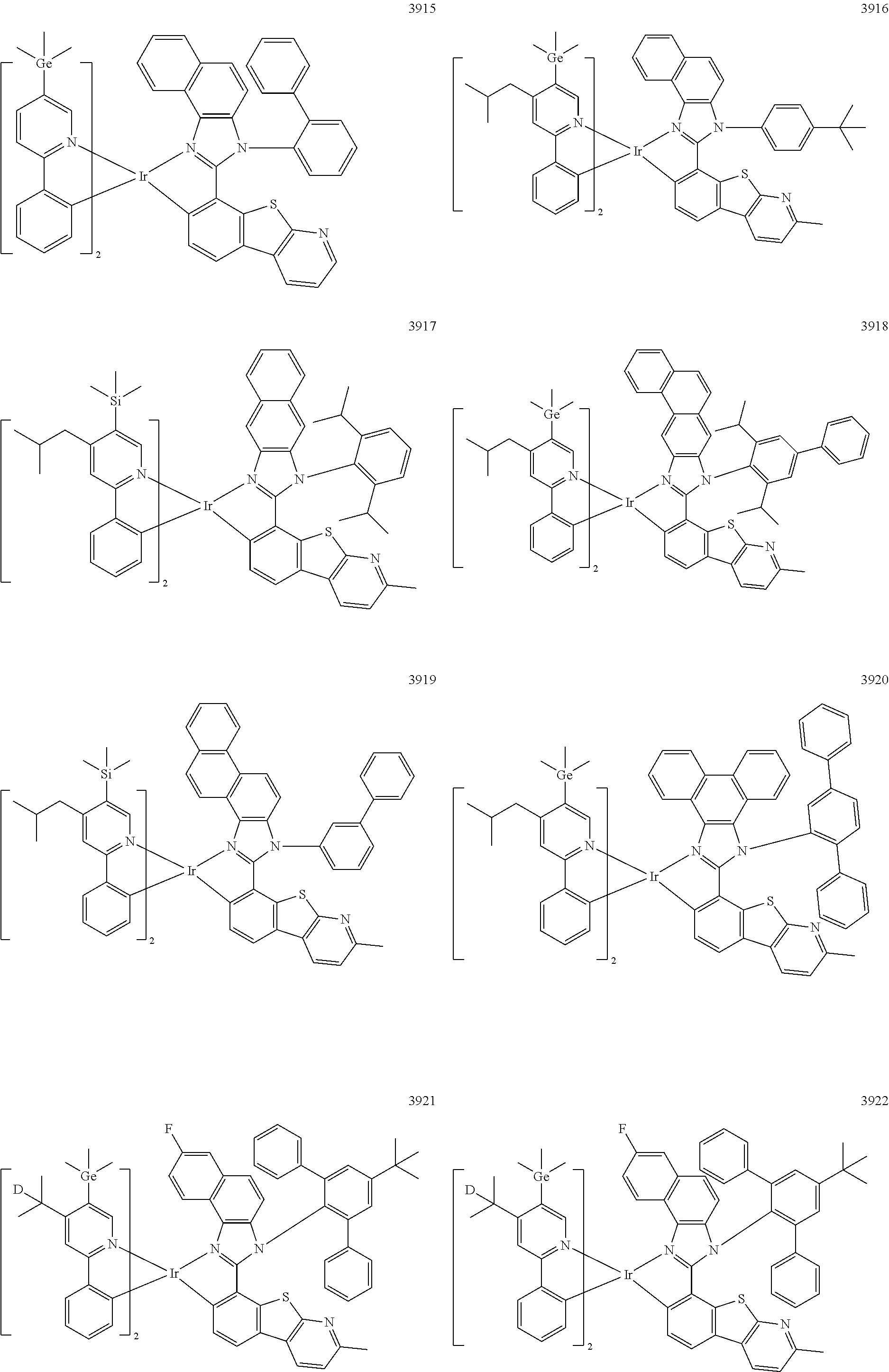

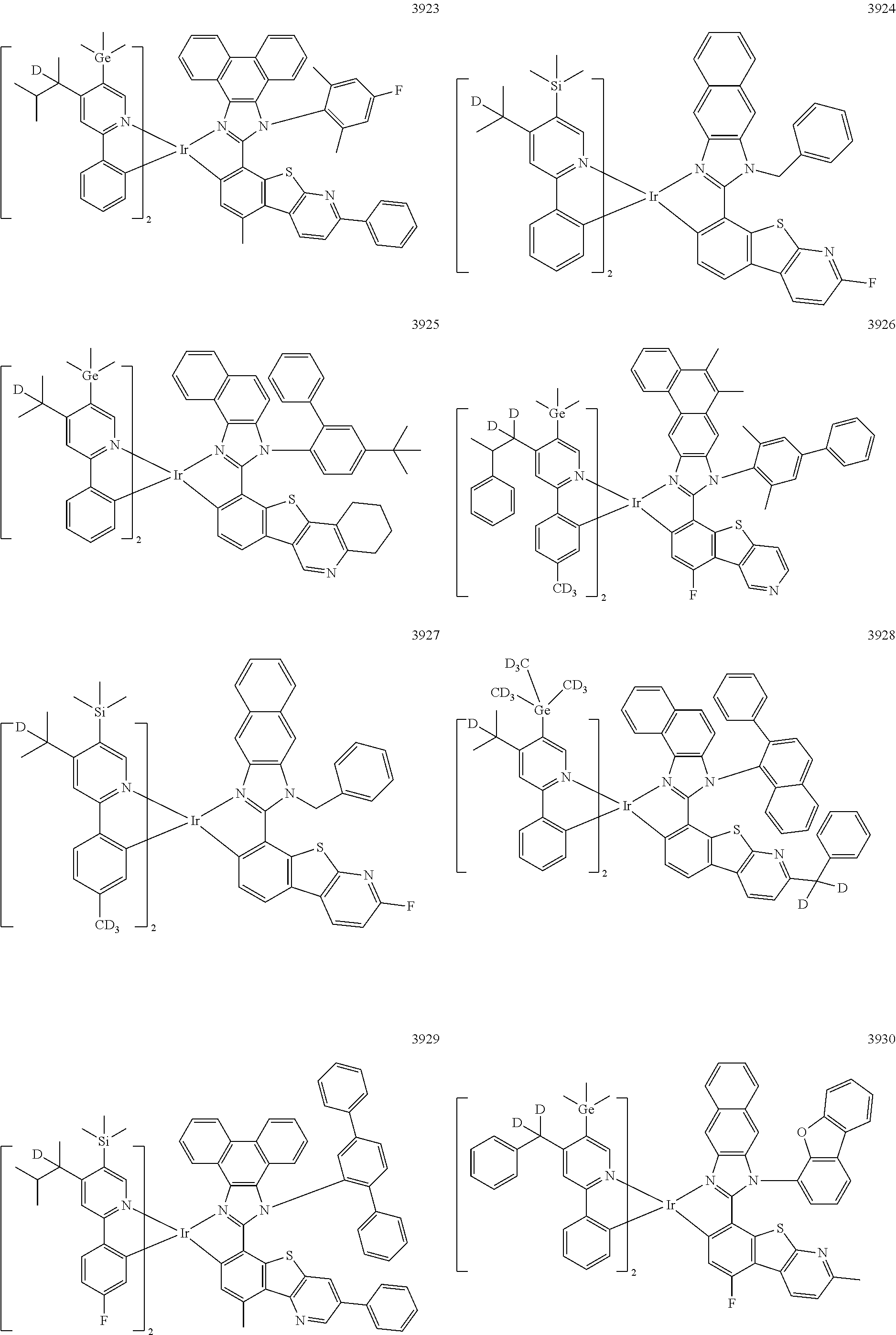

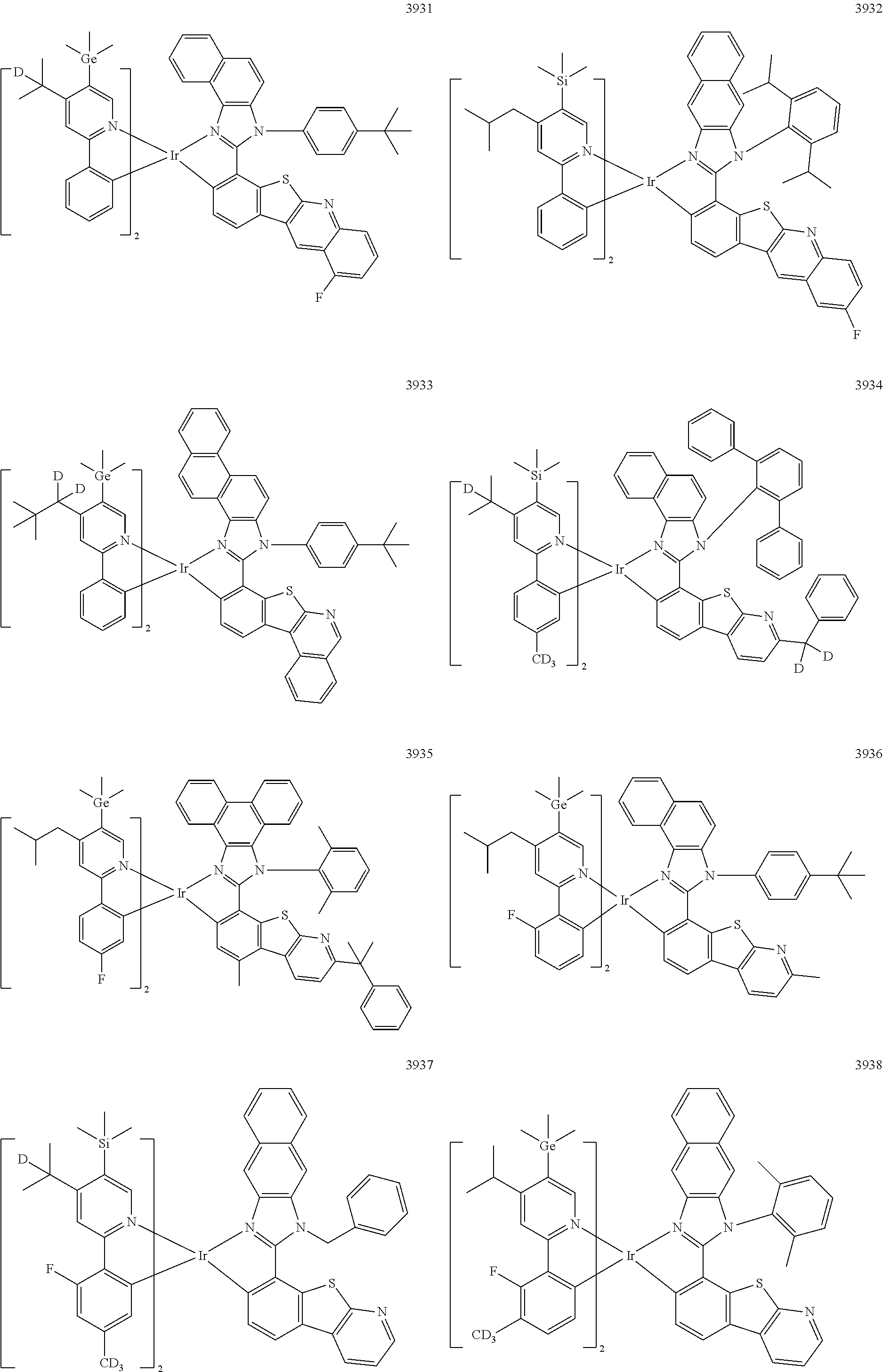

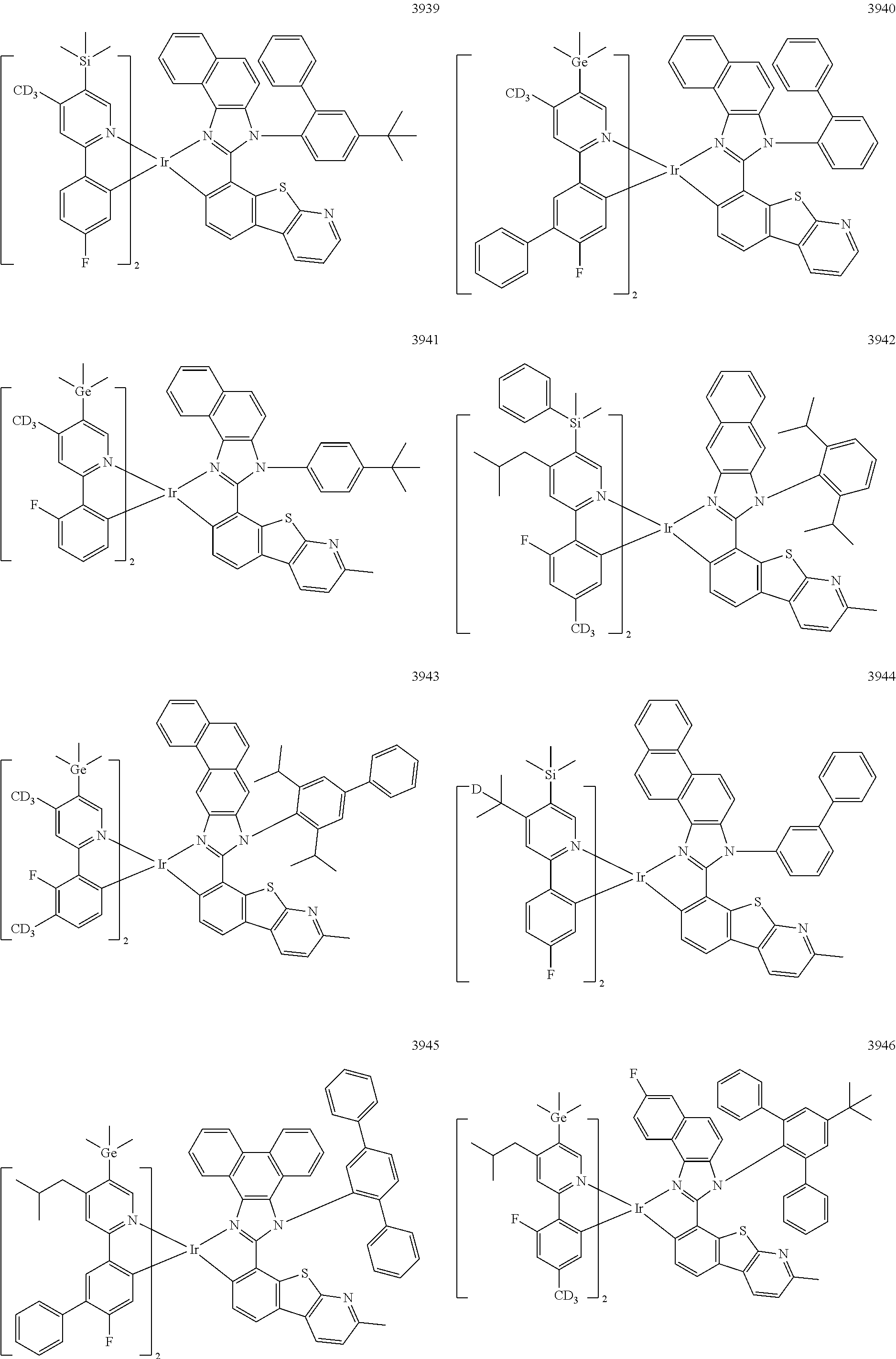

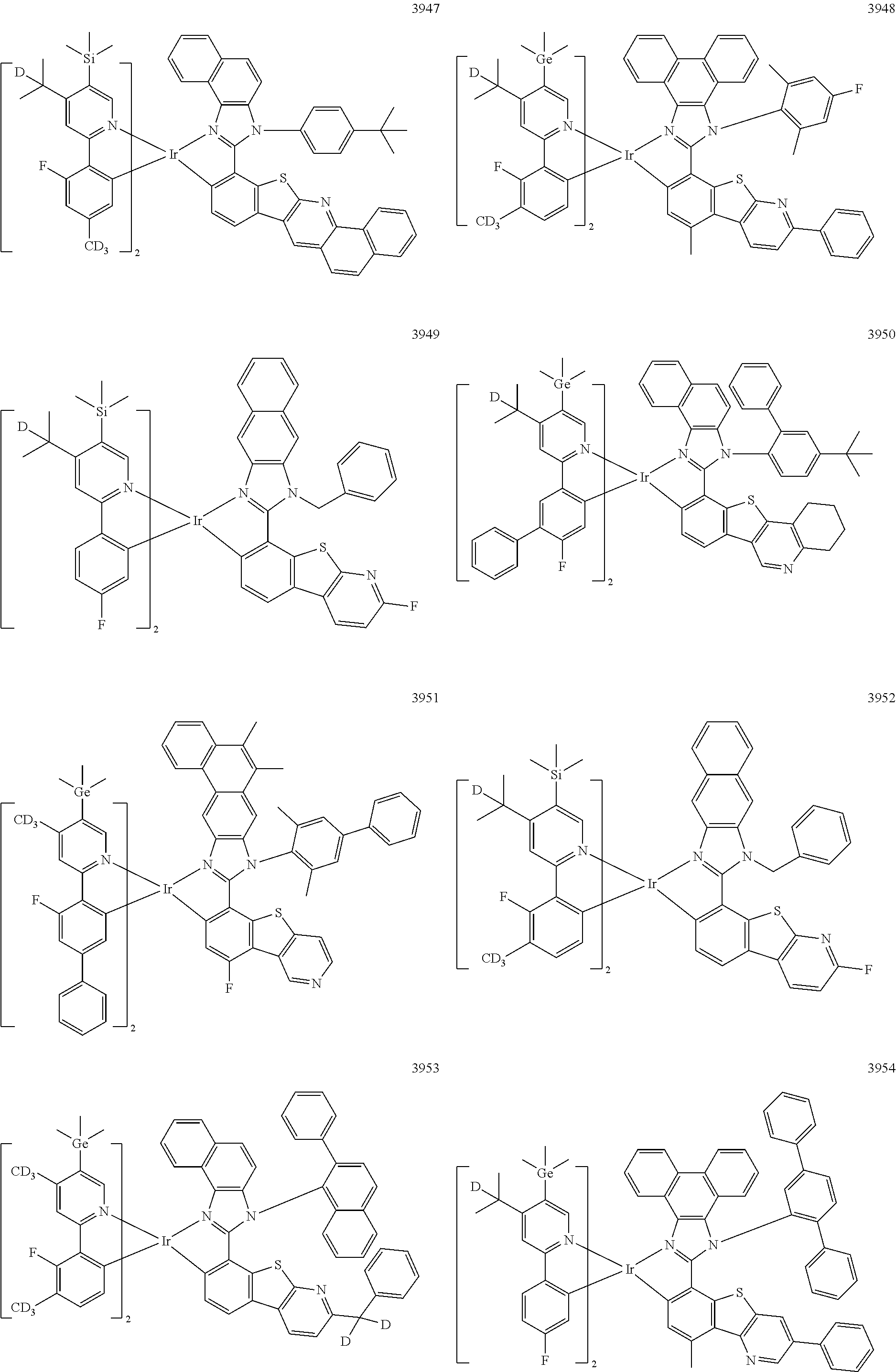

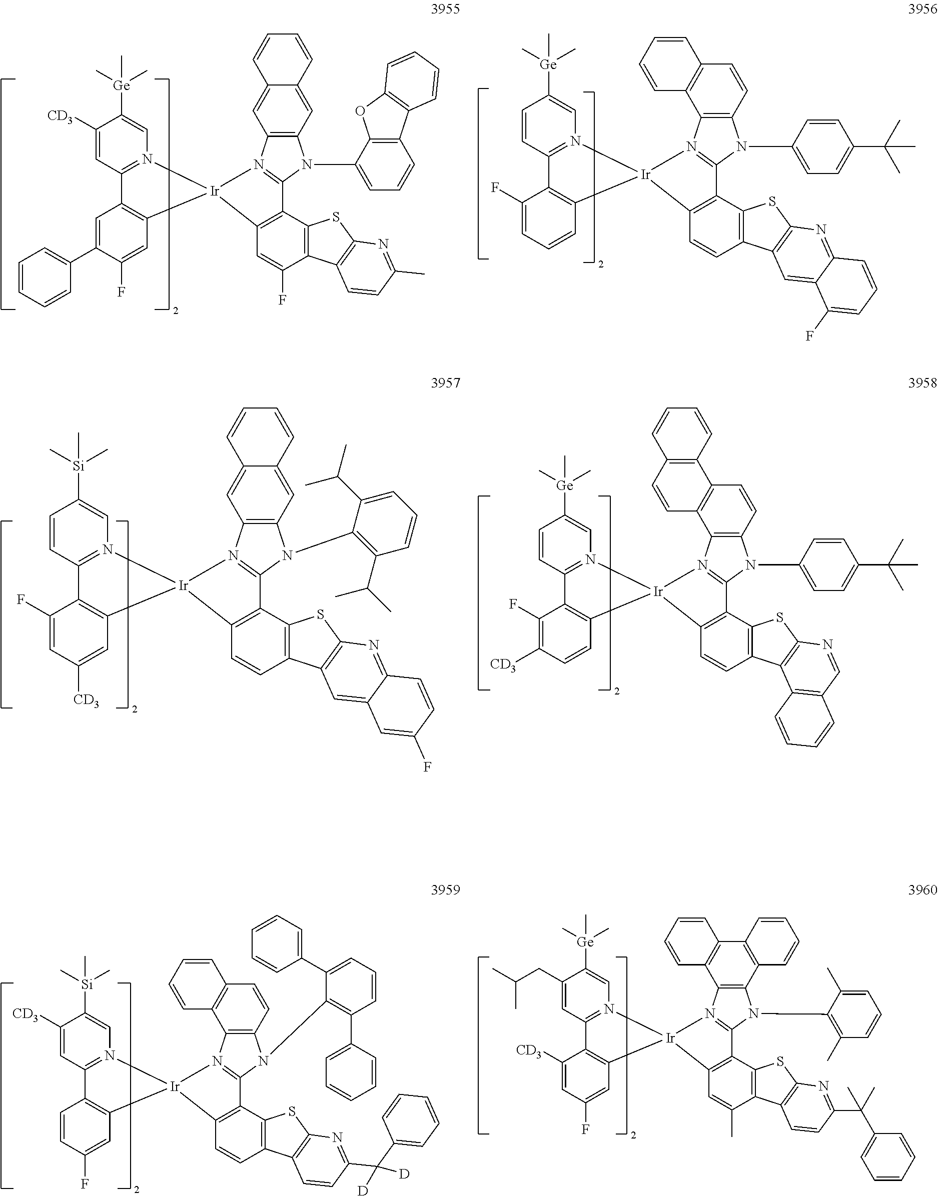

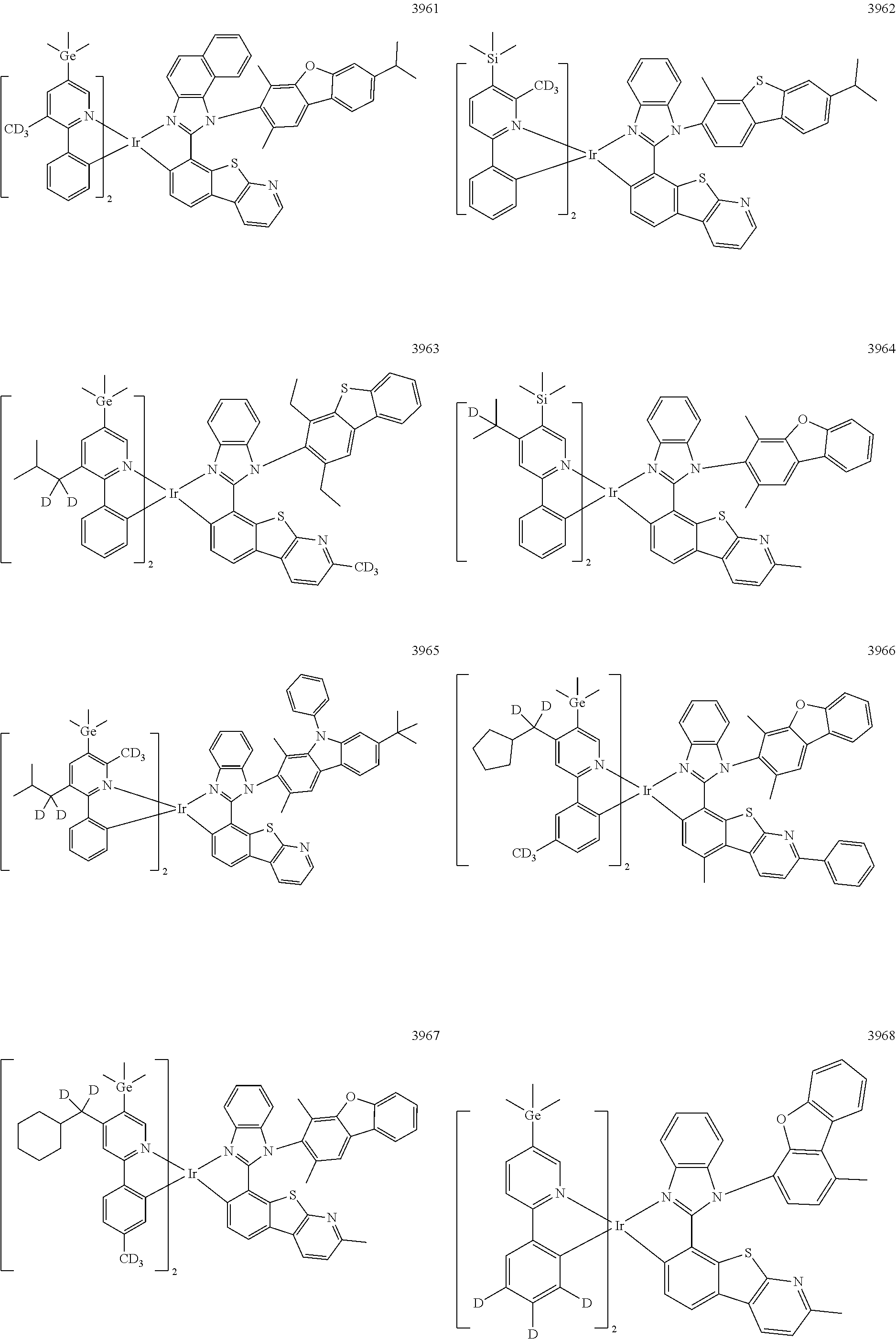

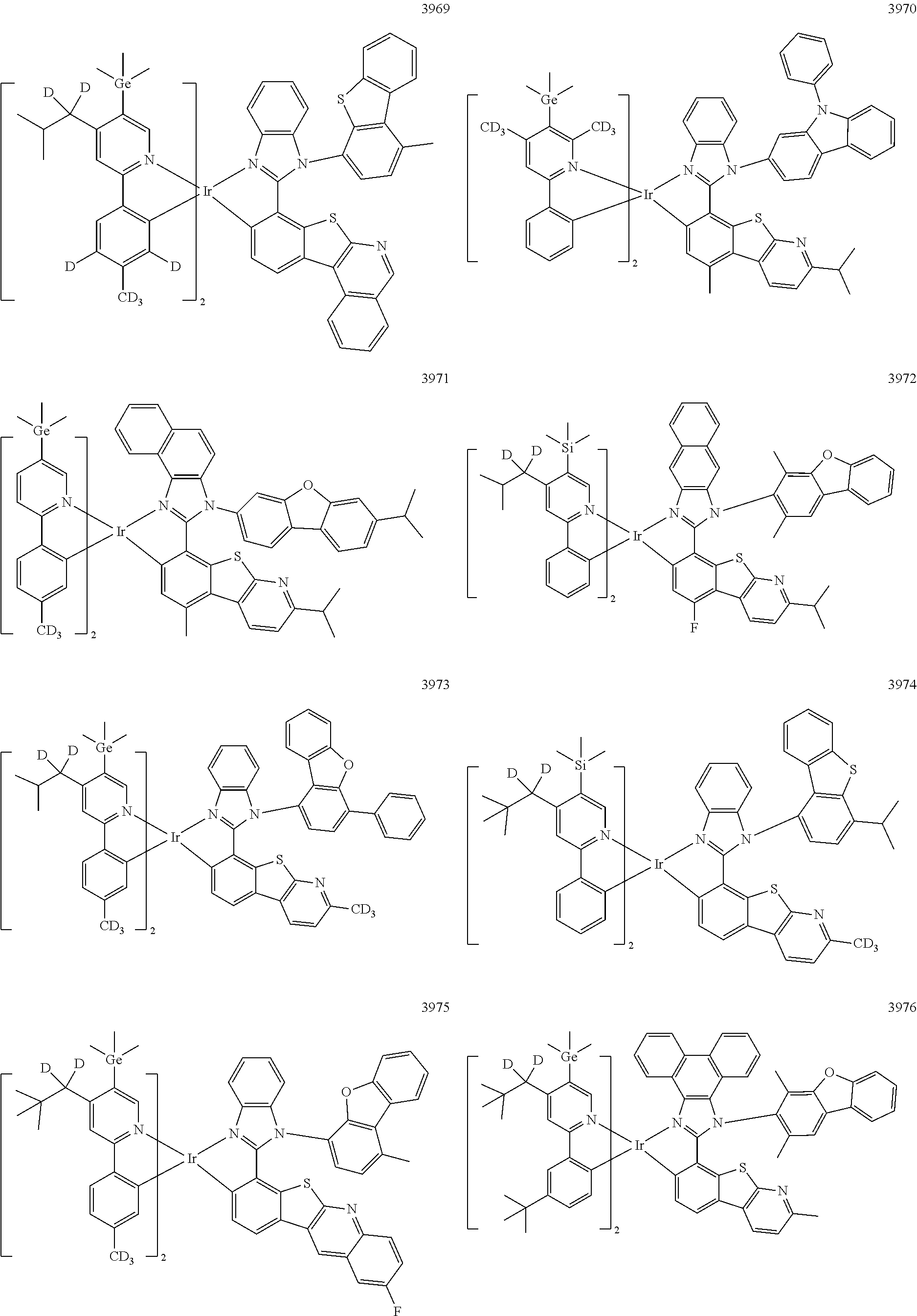

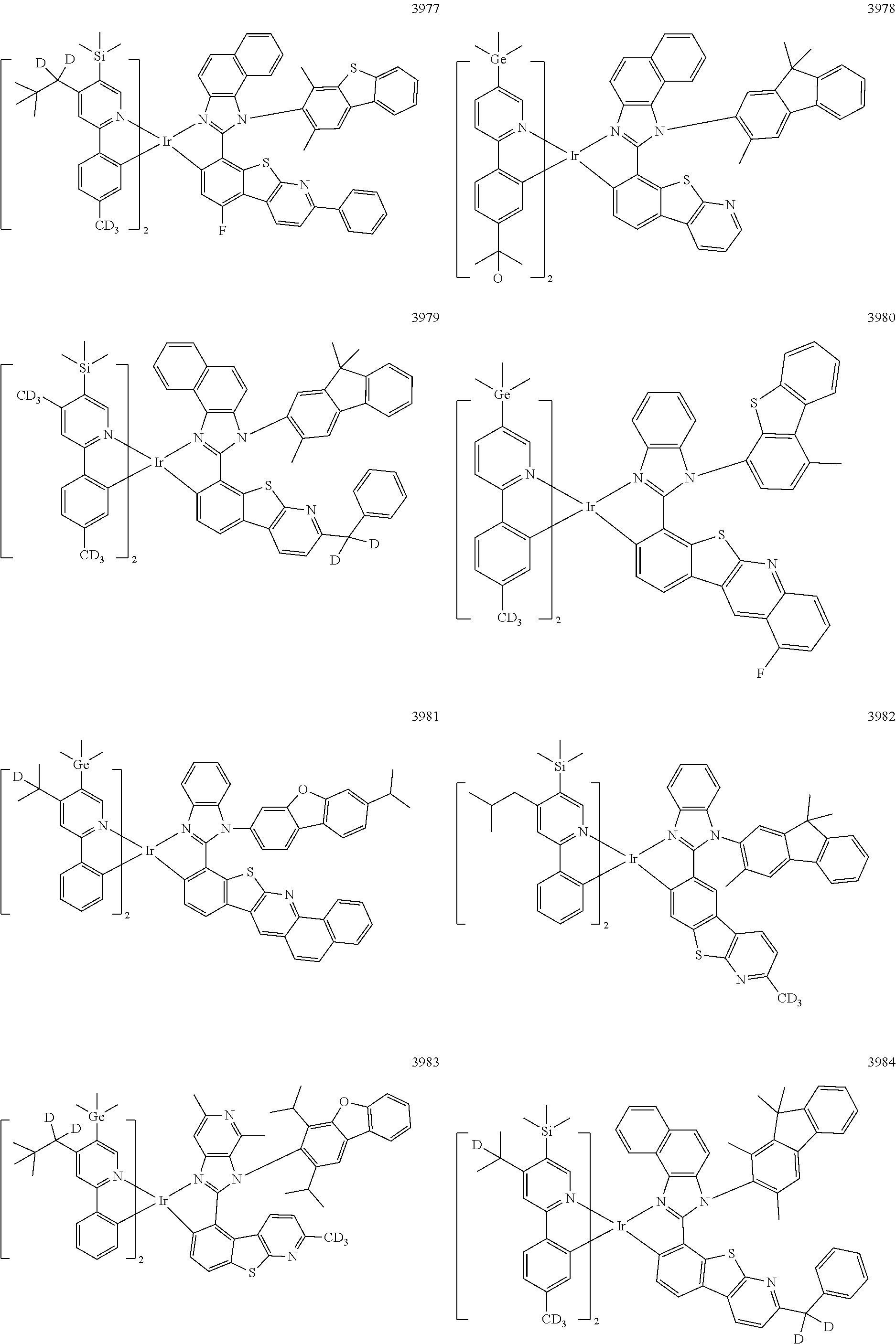

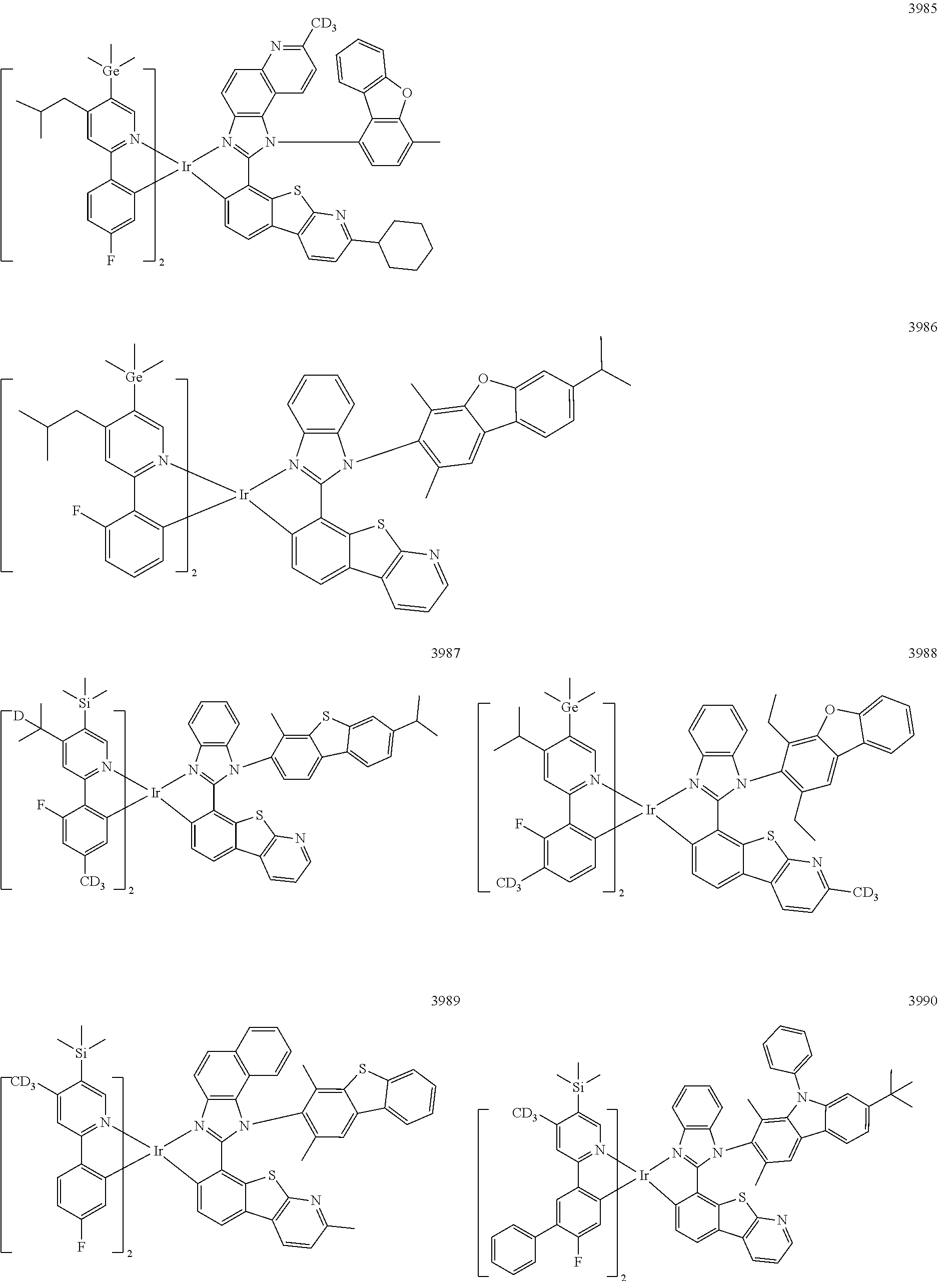

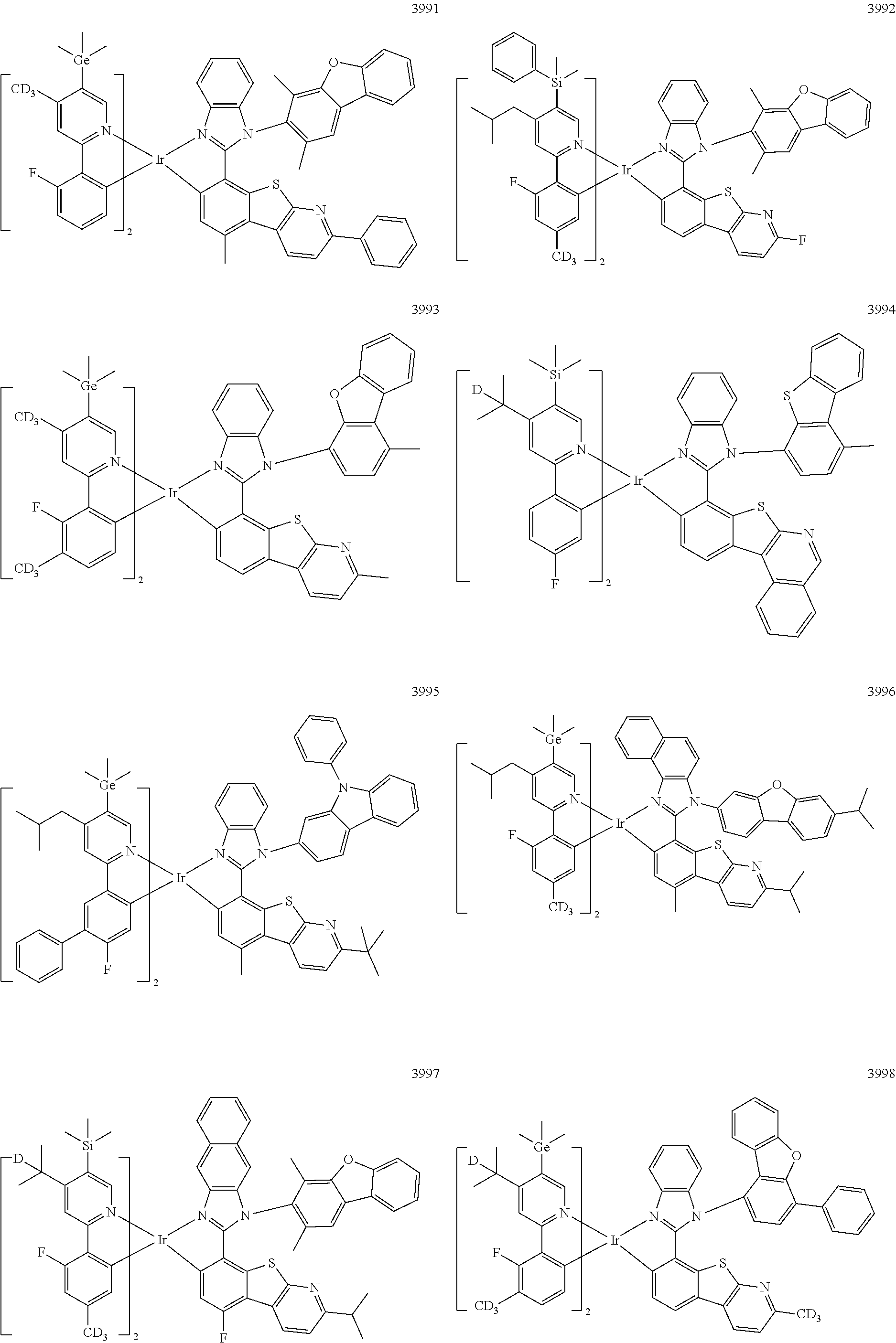

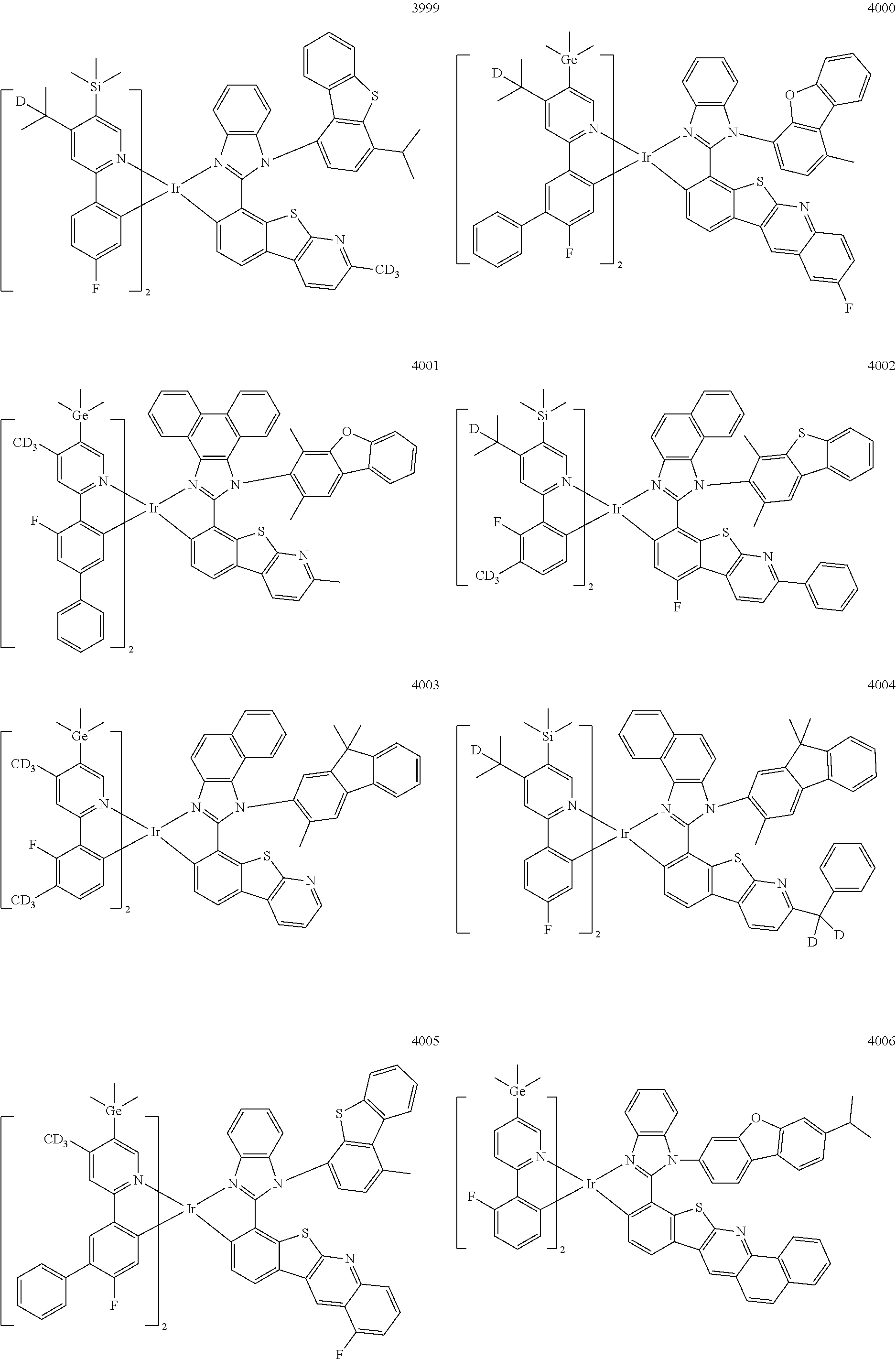

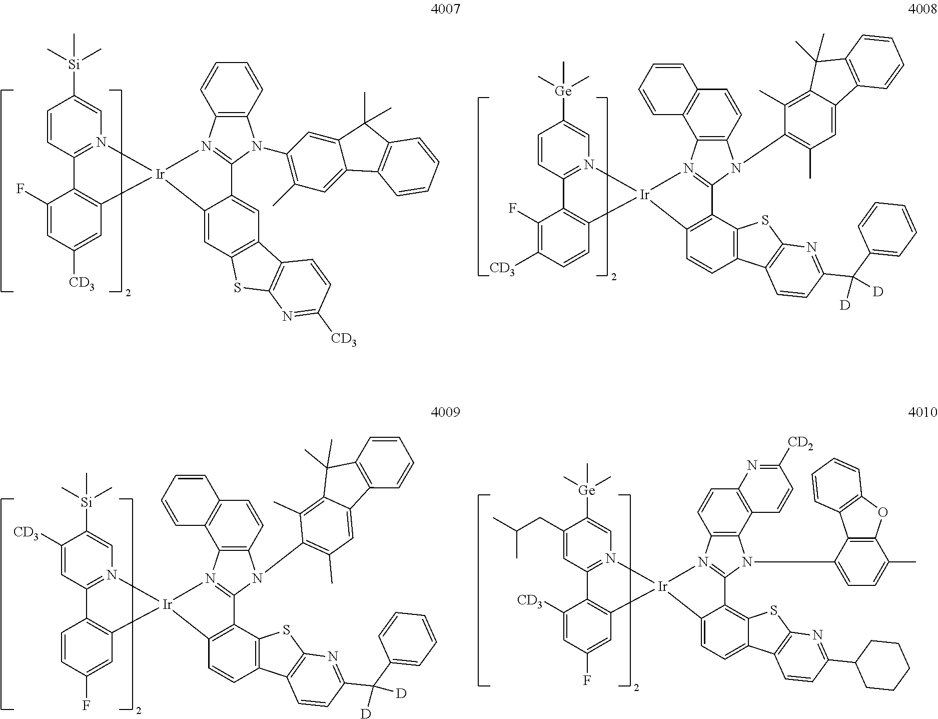

L₁ and L₂ of the organometallic compound represented by Formula 1 may be ligands represented by Formulae 2 and 3, respectively, and n1 and n2, indicating the numbers of L₁ and L₂, respectively, may each independently be 1 or 2. In other words, the organometallic compound includes L₁ (Formula 2) including a group represented by *—X₁₁(R₁₄)(R₁₅)(R₁₆) and L₂ (Formula 3). Accordingly, molecular orientation and charge mobility of the organometallic compound represented by Formula 1 may be significantly improved, and thus external quantum efficiency and lifespan of an electronic device, for example, an organic light-emitting device, including the same may be improved.

Results of evaluating a highest occupied molecular orbital (HOMO) energy level, a lowest unoccupied molecular orbital (LUMO) energy level, a Si energy level, and a T₁ energy level of a part of the organometallic compound represented by Formula 1 by using a Gaussian 09 program involving molecular structure optimization by density functional theory (DFT) based on 1B3LYP are shown in Table 1 below.

TABLE 1

| Compound No. | HOMO(eV) | LUMO(eV) | S₁(eV) | T₁(eV) |
|---|---|---|---|---|
| 1 | −4.723 | −1.151 | 2.872 | 2.528 |
| 5 | −4.719 | −1.145 | 2.874 | 2.523 |
| 6 | −4.702 | −1.133 | 2.868 | 2.523 |
| 11 | −4.719 | −1.173 | 2.857 | 2.517 |
| 12 | −4.673 | −1.131 | 2.843 | 2.513 |
| 14 | −4.707 | −1.181 | 2.844 | 2.511 |
| 15 | −4.744 | −1.171 | 2.873 | 2.532 |
| 37 | −4.704 | −1.152 | 2.856 | 2.558 |
| 184 | −4.721 | −1.139 | 2.871 | 2.552 |
| 212 | −4.794 | −1.255 | 2.831 | 2.536 |
| 295 | −4.710 | −1.154 | 2.856 | 2.545 |
| 982 | −4.706 | 1.149 | 2.862 | 2.554 |
| 1042 | −4.761 | −1.197 | 2.856 | 2.513 |
| 1229 | −4.842 | −1.281 | 2.864 | 2.539 |
| 1525 | −4.728 | −1.129 | 2.900 | 2.530 |
| 1550 | −4.705 | −1.108 | 2.892 | 2.557 |
| 1725 | −4.783 | −1.237 | 2.838 | 2.546 |
| 2610 | −4.769 | −1.273 | 32.849 | 2.558 |
| 2755 | −4.779 | −1.200 | 2.883 | 2.531 |
| 3214 | −4.707 | −1.148 | 2.865 | 2.533 |
| 3275 | −4.755 | −1.238 | 2.850 | 2.402 |
| 3492 | −4.840 | −1.268 | 2.892 | 2.509 |
| 3553 | −4.727 | −1.231 | 2.839 | 2.405 |

From Table 1, it is confirmed that the organometallic compound represented by Formula 1 has such electric characteristics that are suitable for use as a dopant for an electronic device, for example, an organic light-emitting device.

A synthesis method for the organometallic compound represented by Formula 1 would be understood to those of ordinary skill in the art by referring to the following exemplary embodiments.

Therefore, the organometallic compound represented by Formula 1 may be suitable for an organic layer of an organic light-emitting device. For example, the organometallic compound represented by Formula 1 may be suitable as a dopant in an emission layer in the organic layer. Accordingly, another aspect of the present disclosure provides an organic light-emitting device including: a first electrode; a second electrode; and an organic layer disposed between the first electrode and the second electrode and including an emission layer, wherein the organic layer includes at least one organometallic compound represented by Formula 1.

The organic light-emitting device including the organic layer including the organometallic compound represented by Formula 1 may have improved external quantum efficiency and improved lifespan characteristics.

The organometallic compound represented by Formula 1 may be used between a pair of electrodes of the organic light-emitting device. For example, the organometallic compound represented by Formula 1 may be included in the emission layer. Here, the organometallic compound may serve as a dopant, and the emission layer may further include a host (i.e., an amount of the organometallic compound represented by Formula 1 may be smaller than that of the host). The emission layer may emit red light or green light, for example, red light or green light, each having a maximum emission wavelength of 500 nm or more, for example, 500 nm or more and 850 nm or less. For example, the organometallic compound may emit green light.

The expression “(an organic layer) includes at least one organometallic compound” as used herein may include a case in which “(an organic layer) includes identical organometallic compounds represented by Formula 1” and a case in which “(an organic layer) includes two or more different organometallic compounds represented by Formula 1”.

For example, the organic layer may include, as the organometallic compound, only Compound 1. Here, Compound 1 may exist only in the emission layer of the organic light-emitting device. In one or more embodiments, the organic layer may include, as the organometallic compound, Compound 1 and Compound 2. Here, Compound 1 and Compound 2 may exist in a same layer (for example, Compound 1 and Compound 2 may all exist in the emission layer).

The first electrode may be an anode which is a hole injection electrode, and the second electrode may be a cathode which is an electron injection electrode; or the first electrode may be a cathode which is an electron injection electrode, and the second electrode may be an anode which is a hole injection electrode.

For example, in the organic light-emitting device, the first electrode may be an anode, the second electrode may be a cathode, and the organic layer may further include a hole transport region between the first electrode and the emission layer and an electron transport region disposed between the emission layer and the second electrode, wherein the hole transport region may include a hole injection layer, a hole transport layer, an electron blocking layer, a buffer layer, or a combination thereof, and the electron transport region may include a hole blocking layer, an electron transport layer, an electron injection layer, or a combination thereof.

The term “organic layer” as used herein refers to a single layer and/or a plurality of layers disposed between the first electrode and the second electrode of the organic light-emitting device. The “organic layer” may include not only an organic compound, but also an organometallic complex including metal.

FIGURE is a schematic cross-sectional view of an organic light-emitting device 10 according to an embodiment. Hereinafter, the structure of the organic light-emitting device 10 according to an embodiment and a method of manufacturing the organic light-emitting device 10 will be described in connection with the FIGURE. The organic light-emitting device 10 has a structure in which a first electrode 11, an organic layer 15, and a second electrode 19 are stacked in the stated order.

A substrate may be additionally disposed under the first electrode 11 or above the second electrode 10. For use as the substrate, a substrate used in a typical organic light-emitting device in the related art may be used, and in this regard, the substrate may be a glass substrate or a plastic substrate, each having excellent mechanical strength, thermal stability, transparency, surface smoothness, ease of handling, and water resistance.

The first electrode 11 may be formed by depositing or sputtering a material for forming the first electrode 11 on the substrate. The first electrode 11 may be an anode. A material for forming the first electrode 11 may include a material with a high work function to facilitate hole injection. The first electrode 11 may be a reflective electrode, a semi-transmissive electrode, or a transmissive electrode. The material for forming the first electrode 11 may include indium tin oxide (ITO), indium zinc oxide (IZO), tin oxide (SnO₂), zinc oxide (ZnO), or the like. In one or more embodiments, the material for forming the first electrode 11 may include metal or metal alloy, such as magnesium (Mg), aluminum (Al), aluminum-lithium (Al—Li), calcium (Ca), magnesium-indium (Mg—In), and magnesium-silver (Mg—Ag).

The first electrode 11 may have a single-layered structure, or a multi-layered structure including two or more layers. For example, the first electrode 11 may have a three-layered structure of ITO/Ag/ITO.

The organic layer 15 may be disposed on the first electrode 11.

The organic layer 15 may include: a hole transport region; an emission layer; and an electron transport region.

The hole transport region may be disposed between the first electrode 11 and the emission layer.

The hole transport region may include a hole injection layer, a hole transport layer, an electron blocking layer, a buffer layer, or a combination thereof.

The hole transport region may include a hole injection layer only, or a hole transport layer only. In one or more embodiments, the hole transport region may have a hole injection layer/hole transport layer structure or a hole injection layer/hole transport layer/electron blocking layer structure, wherein for each structure, constituting layers are sequentially stacked from the first electrode 11 in this stated order.

When the hole transport region includes a hole injection layer, the hole injection layer may be formed on the first electrode 11 by using various methods, such as vacuum deposition, spin coating, casting, Langmuir-Blodgett (LB) deposition, and the like.

When the hole injection layer is formed by vacuum deposition, the deposition may be performed at a deposition temperature of about 100° C. to about 500° C., a vacuum degree of about 10⁻⁸ torr to about 10⁻³ torr, and a deposition speed of about 0.01 angstrom per second (Å/sec) to about 100 Å/sec by taking into account a compound for forming a hole injection layer and a structure and thermal characteristics of an emission layer to be formed.

When the hole injection layer is formed by spin coating, the coating may be performed at a coating speed of about 2,000 revolutions per minute (rpm) to about 5,000 rpm and at a heat treatment temperature of about 80° C. to 200° C. for the removal of a solvent after coating by taking into account a compound for forming a hole injection layer and a structure and thermal characteristics of a hole injection layer to be formed.

Conditions for forming the hole transport layer and the electron blocking layer may be referred to those for forming the hole injection layer.

The hole transport region may include, for example, m-MTDATA, TDATA, 2-TNATA, NPB, β-NPB, TPD, spiro-TPD, spiro-NPB, methylated-NPB, TAPC, HMTPD, 4,4′,4″-tris(N-carbazolyl)triphenylamine) (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, a compound represented by Formula 202, or a combination thereof:

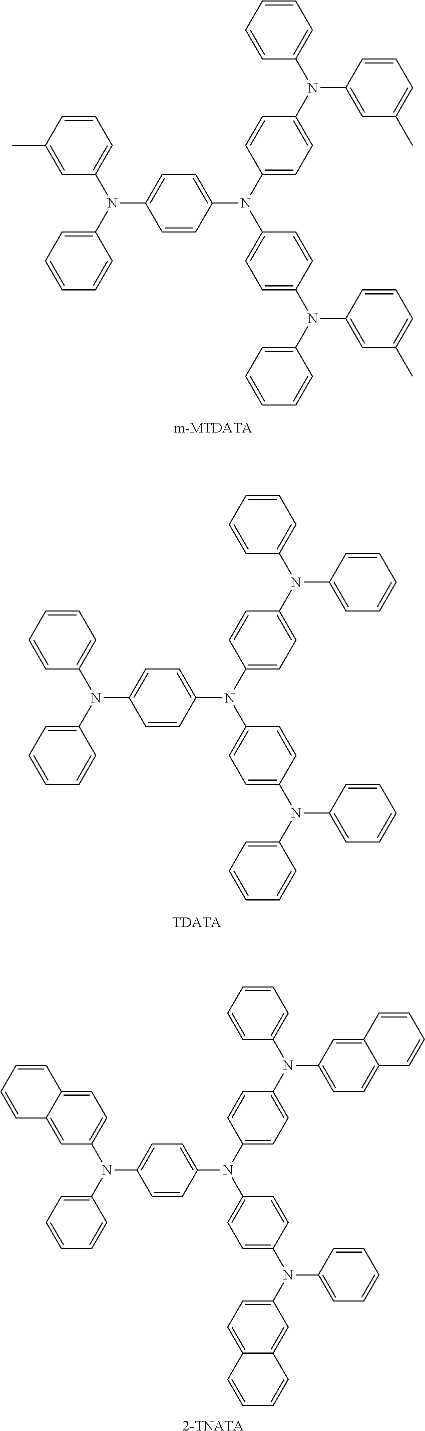

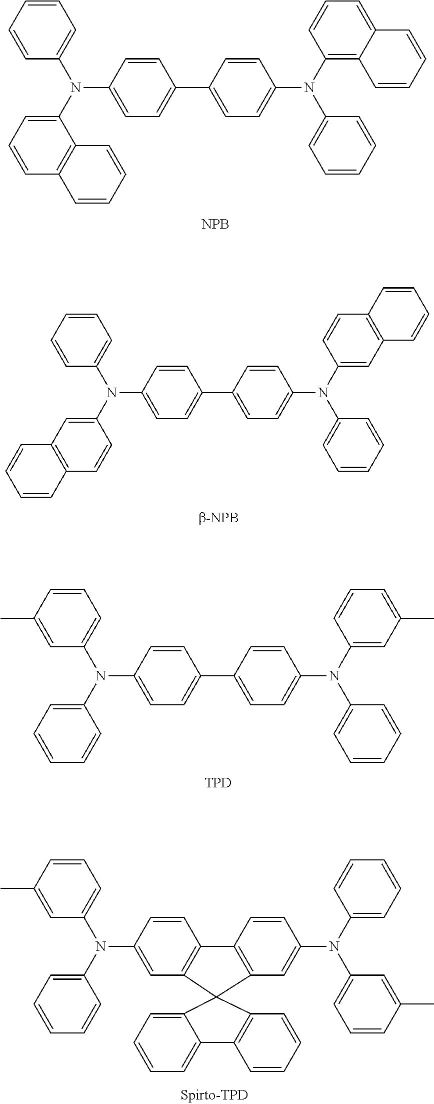

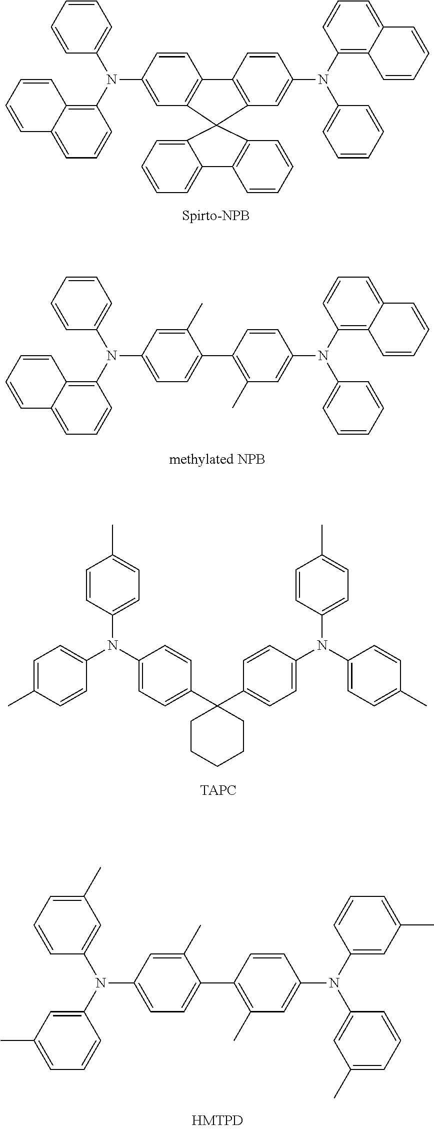

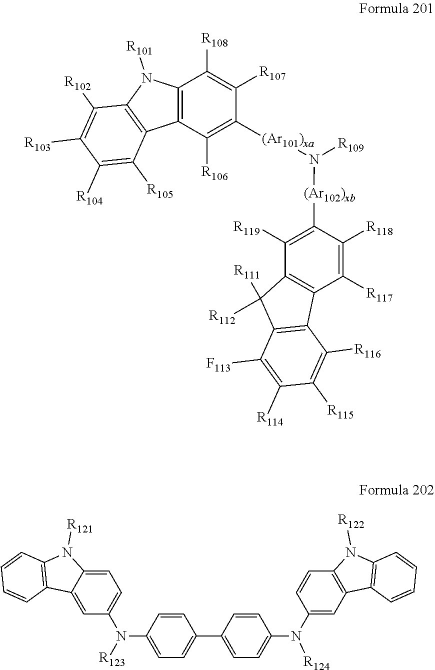

In Formula 201, Ar₁₀₁ and Ar₁₀₂ may each independently be a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, or a pentacenylene group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, or a combination thereof.

In Formula 201, xa and xb may each independently be an integer from 0 to 5, or may be 0, 1, or 2. For example, xa may be 1, and xb may be 0.

In Formulae 201 and 202, R₁₀₁ to R₁₀₈, R₁₁₁ to R₁₁₉, and R₁₂₁ to R₁₂₄ may each independently be:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, a hexyl group, or the like), or a C₁-C₁₀ alkoxy group (for example, a methoxy group, an ethoxy group, a propoxy group, a butoxy group, a pentoxy group, or the like);
a C₁-C₁₀ alkyl group or a C₁-C₁₀ alkoxy group, each substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, or a combination thereof; or
a phenyl group, a naphthyl group, an anthracenyl group, a fluorenyl group, or a pyrenyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, or a combination thereof.

In Formula 201, R₁₀₉ may be a phenyl group, a naphthyl group, an anthracenyl group, or a pyridinyl group, each unsubstituted or substituted with deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, a pyridinyl group, or a combination thereof.

In one or more embodiments, the compound represented by Formula 201 may be represented by Formula 201A:

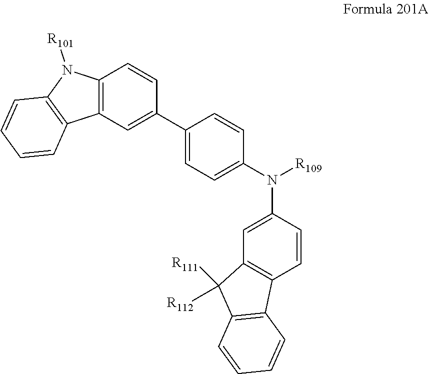

In Formula 201A, R₁₀₁, R₁₁₁, R₁₁₂, and R₁₀₉ may each be understood by referring to the corresponding descriptions thereof provided herein.

For example, the compound represented by Formula 201 and the compound represented by Formula 202 may include Compounds HT1 to HT20:

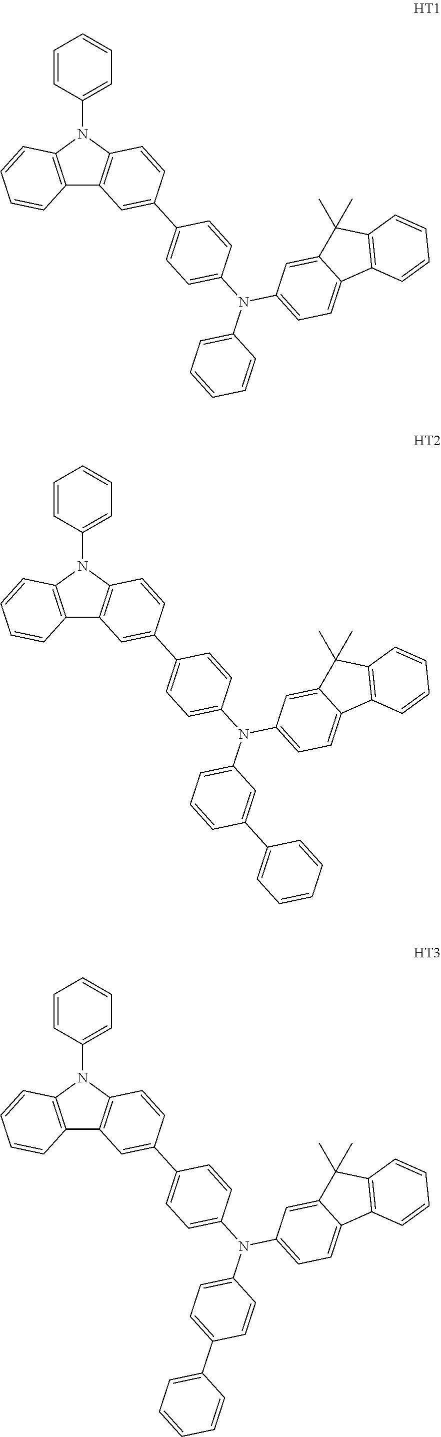 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

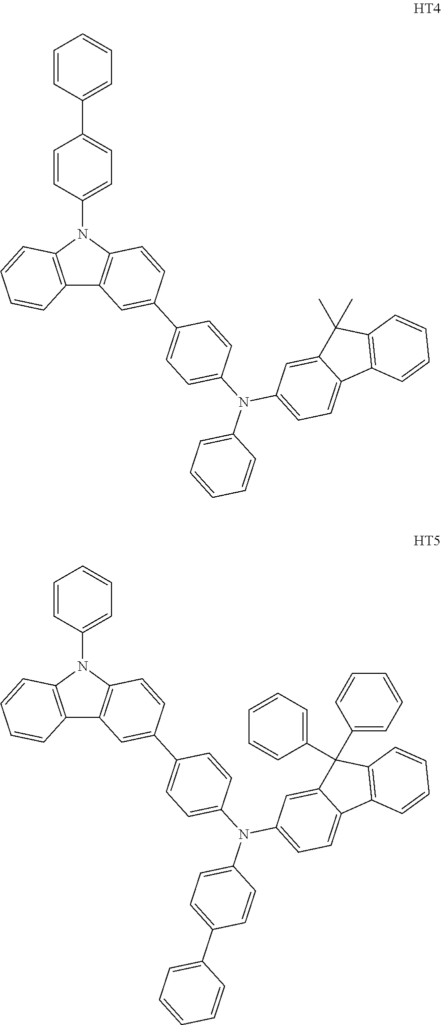 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

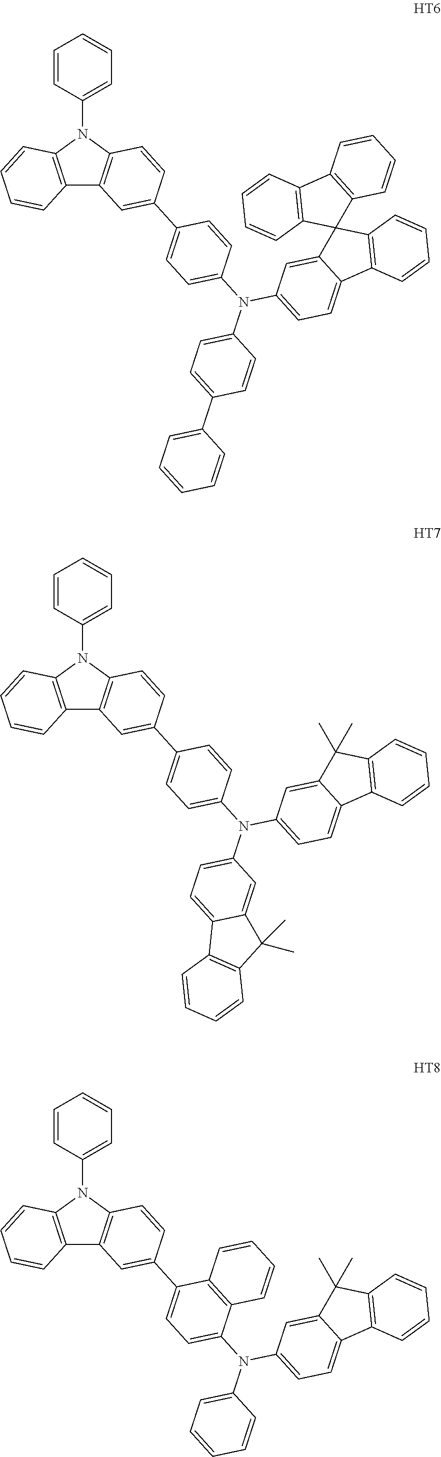 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

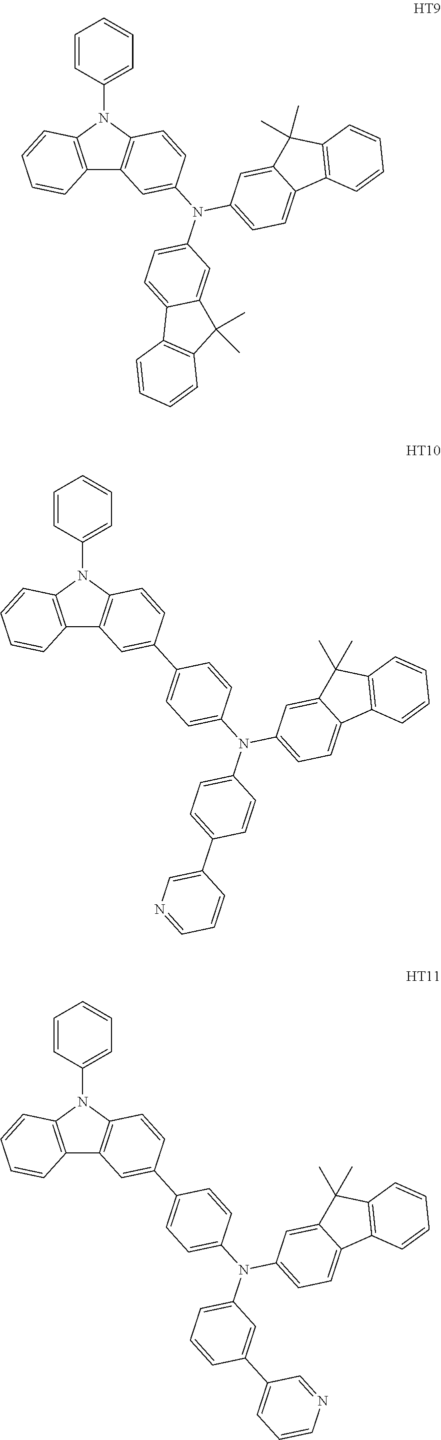 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

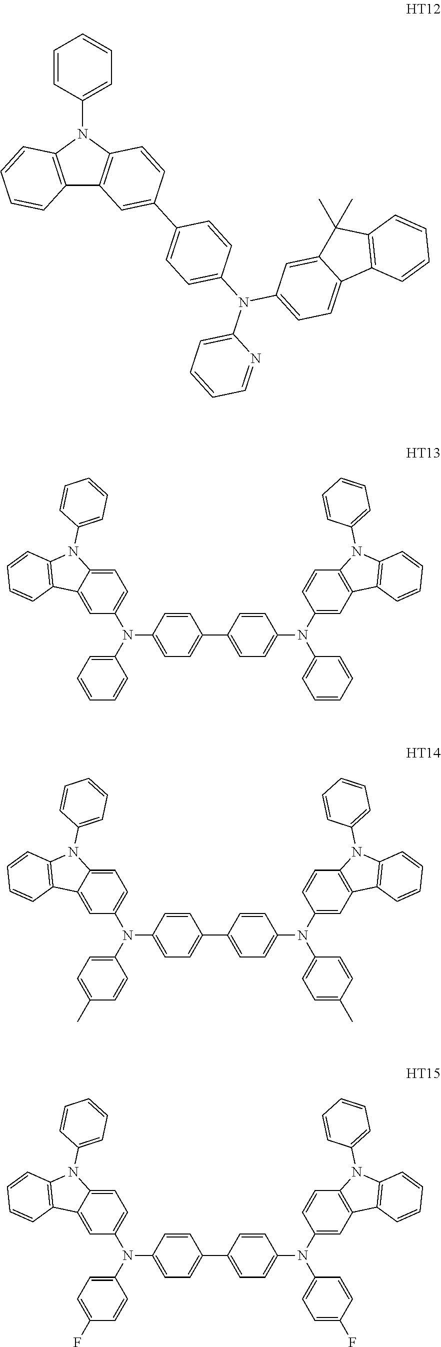 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

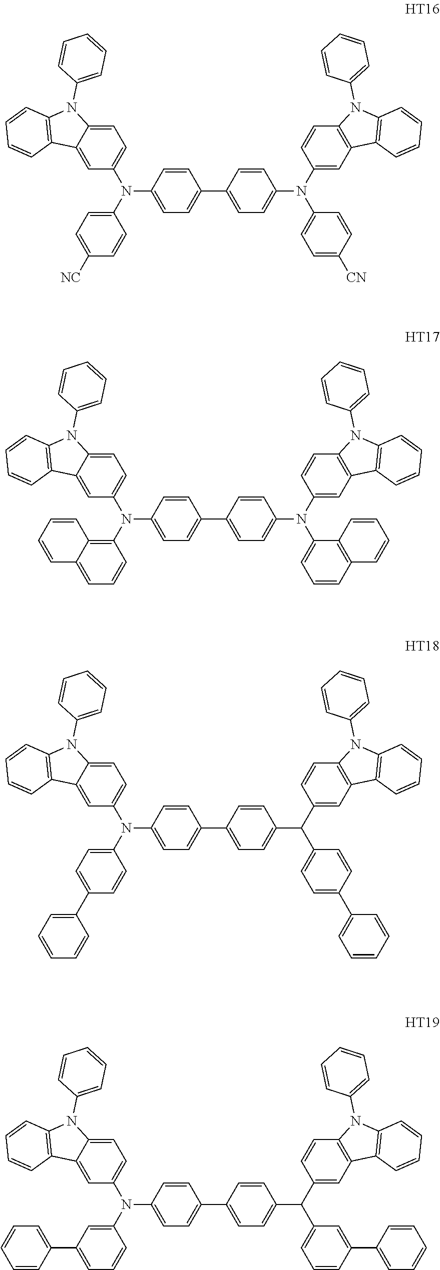 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(C(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(C(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

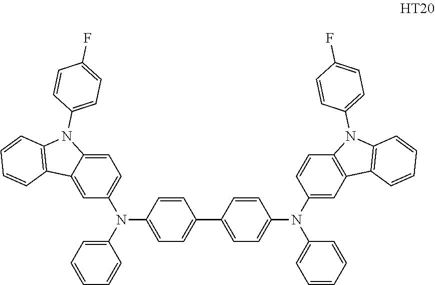 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10,000 Å, for example, about 100 Å to about 1,000 Å. When the hole transport region includes at least one layer that is a hole injection layer or a hole transport layer, a thickness of the hole injection layer may be in a range of about 100 Å to about 10,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously (e.g., heterogeneously) dispersed in the hole transport region.

The charge-generation material may be, for example, a p-dopant. The p-dopant may be one of a quinone derivative, a metal oxide, and a cyano group-containing compound. For example, non-limiting examples of the p-dopant include: a quinone derivative, such as tetracyanoquinodimethane (TCNQ), 2,3,5,6-tetrafluoro-7,7,8,8-tetracyanoquinodimethane (F4-TCNQ), or F6-TCNNQ; a metal oxide, such as a tungsten oxide or a molybdenum oxide; and a cyano group-containing compound such as Compound HT-D1:

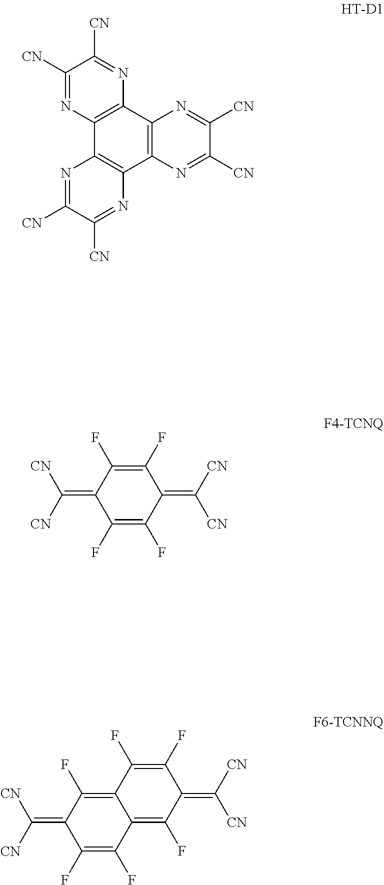

The hole transport region may further include a buffer layer.

The buffer layer may increase efficiency by compensating for an optical resonance distance according to the wavelength of light emitted by the emission layer.

In one or more embodiments, when the hole transport region includes an electron blocking layer, a material for forming the electron blocking layer may include the above-mentioned material for forming the hole transport region, a host material described below, or a combination thereof. For example, when the hole transport region includes an electron blocking layer, a material for forming the electron blocking layer may be mCP described below.

An emission layer may be formed on the hole transport region by using methods, such as vacuum deposition, spin coating, casting, LB, or the like. When the emission layer is formed by vacuum deposition and spin coating, the deposition conditions and the coating conditions may vary depending on a compound used, but may be generally selected within a range of conditions almost identical to the formation of the hole injection layer.

The emission layer may include a host and a dopant, and the dopant may include the organometallic compound represented by Formula 1.

The host may include TPBi, TBADN, AND (also referred to as “DNA”), CBP, CDBP, TCP, mCP, Compound H50, Compound H51, Compound H52, or a combination thereof:

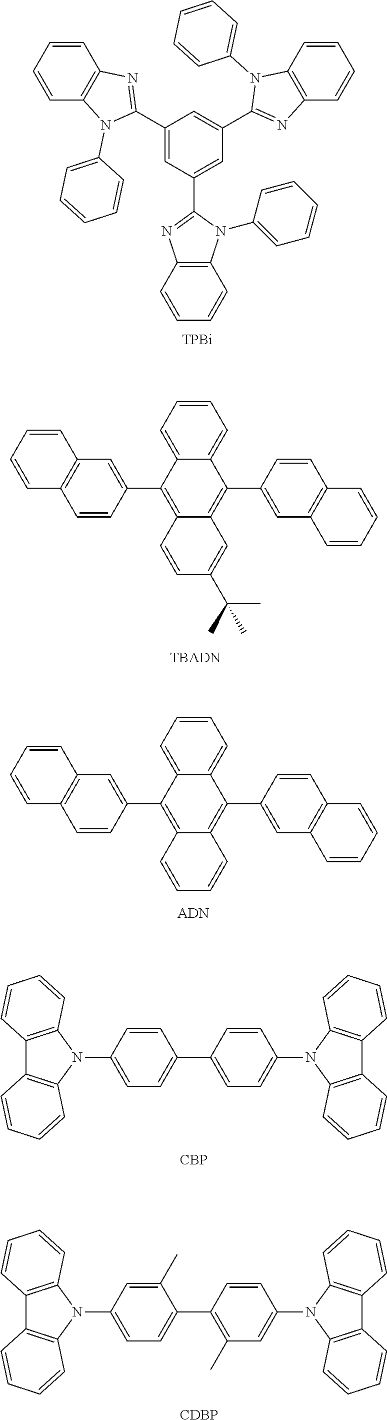

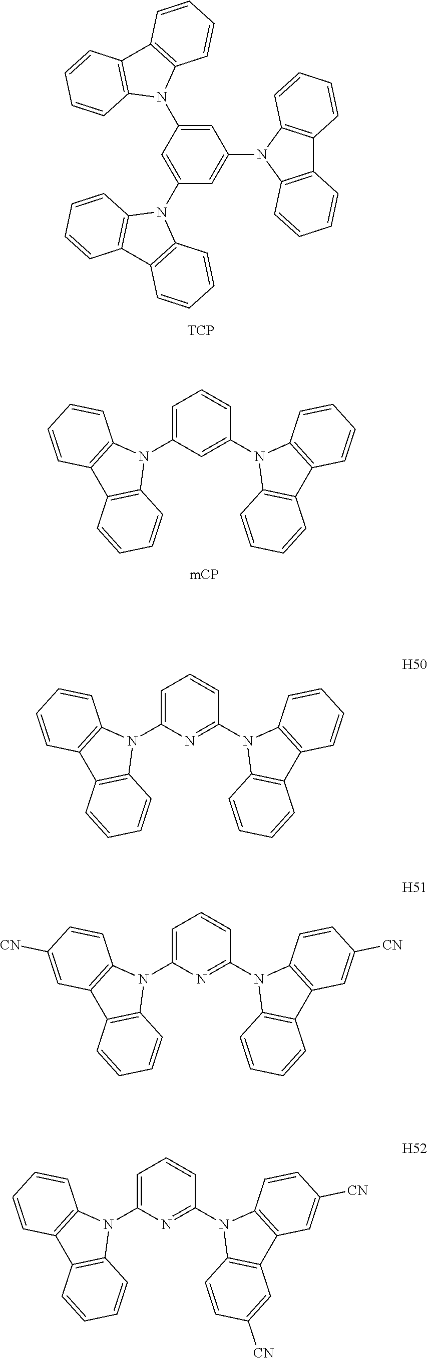

When the organic light-emitting device 10 is a full-color organic light-emitting device, the emission layer may be patterned into a red emission layer, a green emission layer, or a blue emission layer, according to a sub-pixel. In one or more embodiments, the emission layer may have a stacked structure of a red emission layer, a green emission layer, and/or a blue emission layer to emit white light.

When the emission layer includes a host and a dopant, an amount of the dopant may be in a range of about 0.01 parts by weight to about 15 parts by weight based on 100 parts by weight of the host.

A thickness of the emission layer may be in a range of about 100 Å to about 1,000 Å, for example, about 200 Å to about 600 Å. When the thickness of the emission layer is within this range, excellent light-emission characteristics may be obtained without a substantial increase in driving voltage.

Next, an electron transport region may be disposed on the emission layer.

The electron transport region may include a hole blocking layer, an electron transport layer, an electron injection layer, or a combination thereof.

For example, electron transport region may have a hole blocking layer/electron transport layer/electron injection layer structure or an electron transport layer/electron injection layer structure. The electron transport layer may have a single-layered structure or a multi-layered structure having two or more different materials.

Conditions for forming a hole blocking layer, an electron transport layer, and an electron injection layer in the electron transport region may be referred to those for forming the hole injection layer.

When the electron transport region includes a hole blocking layer, the hole blocking layer may include, for example, BCP, Bphen, BAlq, or a combination thereof.

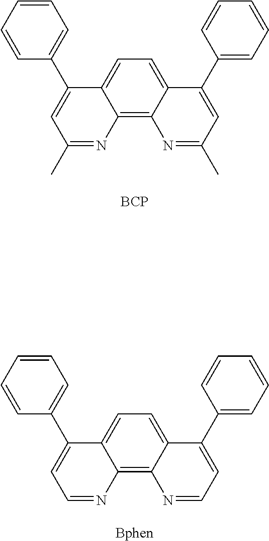

A thickness of the hole blocking layer may be in a range of about 20 Å to about 1,000 Å, for example, about 30 Å to about 300 Å. When the thickness of the hole blocking layer is within the range described above, excellent hole blocking characteristics may be obtained without a substantial increase in driving voltage.

The electron transport layer may include BCP, Bphen, Alq₃, BAlq, TAZ, NTAZ, or a combination thereof:

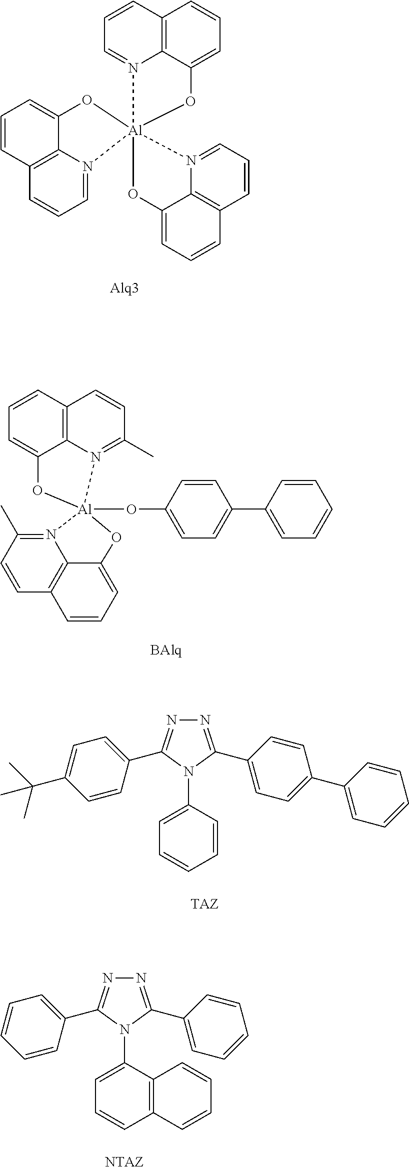

In one or more embodiments, the electron transport layer may include one of Compounds ET1 to ET25, or a combination thereof:

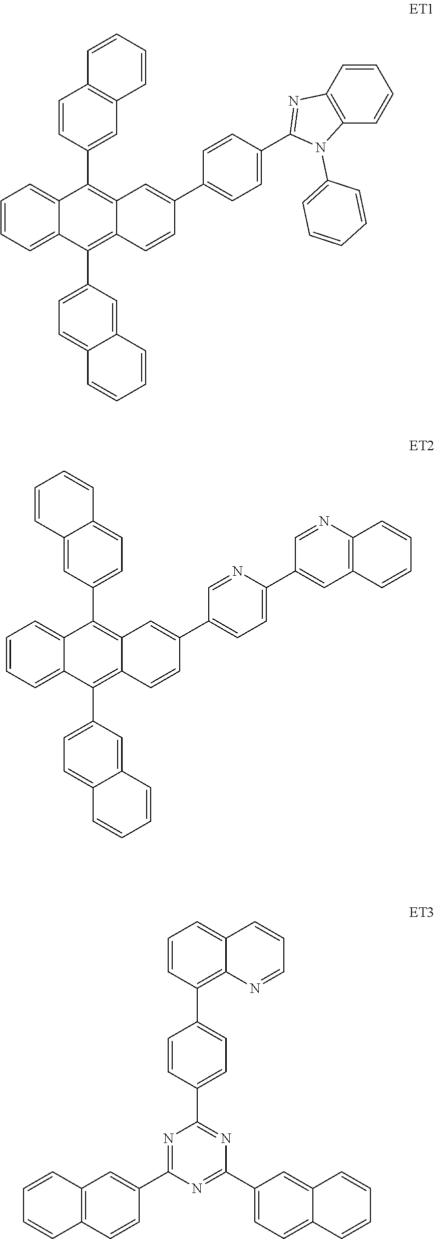 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

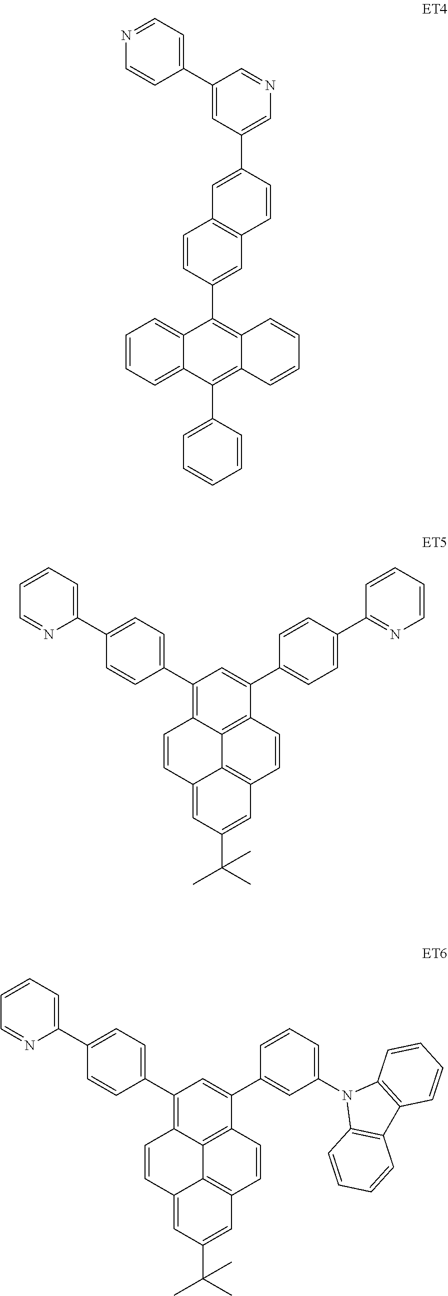 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

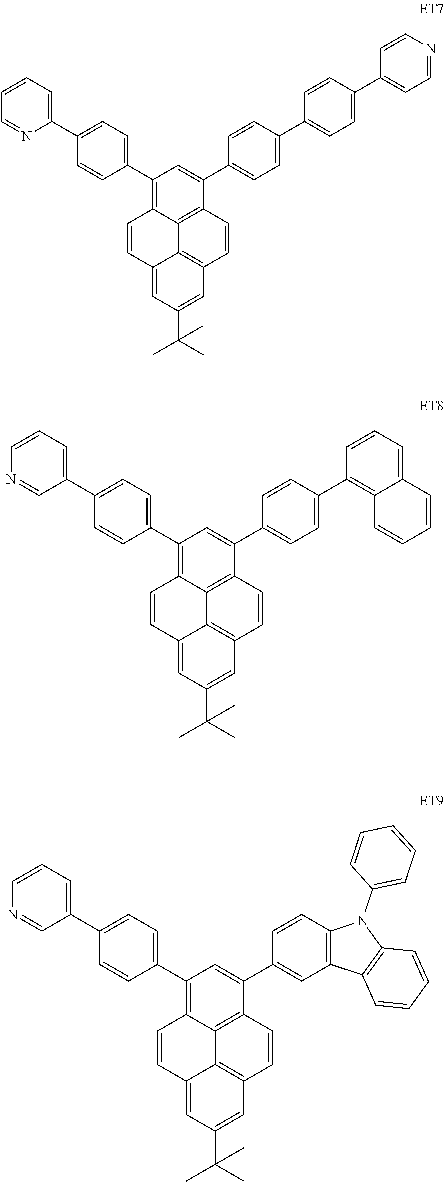 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

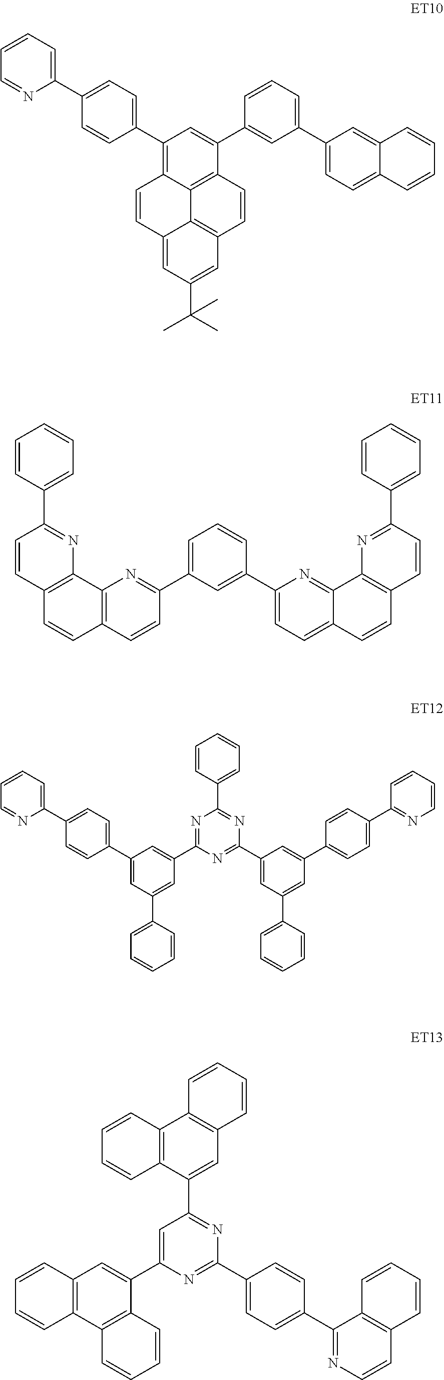 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; c1ccc2c(-c3ccc(-c4nc(-c5cc6ccccc6c6ccccc56)cc(-c5cc6ccccc6c6ccccc56)n4)cc3)nccc2c1]

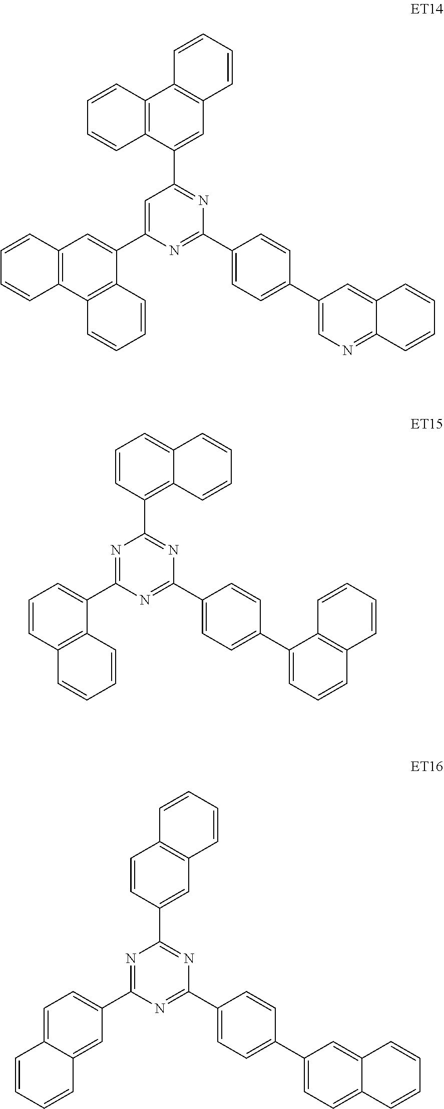 [SMILES: c1ccc2ncc(-c3ccc(-c4nc(-c5cc6ccccc6c6ccccc56)cc(-c5cc6ccccc6c6ccccc56)n4)cc3)cc2c1 ; c1ccc2c(-c3ccc(-c4nc(-c5cccc6ccccc56)nc(-c5cccc6ccccc56)n4)cc3)cccc2c1 ; c1ccc2cc(-c3ccc(-c4nc(-c5ccc6ccccc6c5)nc(-c5ccc6ccccc6c5)n4)cc3)ccc2c1]

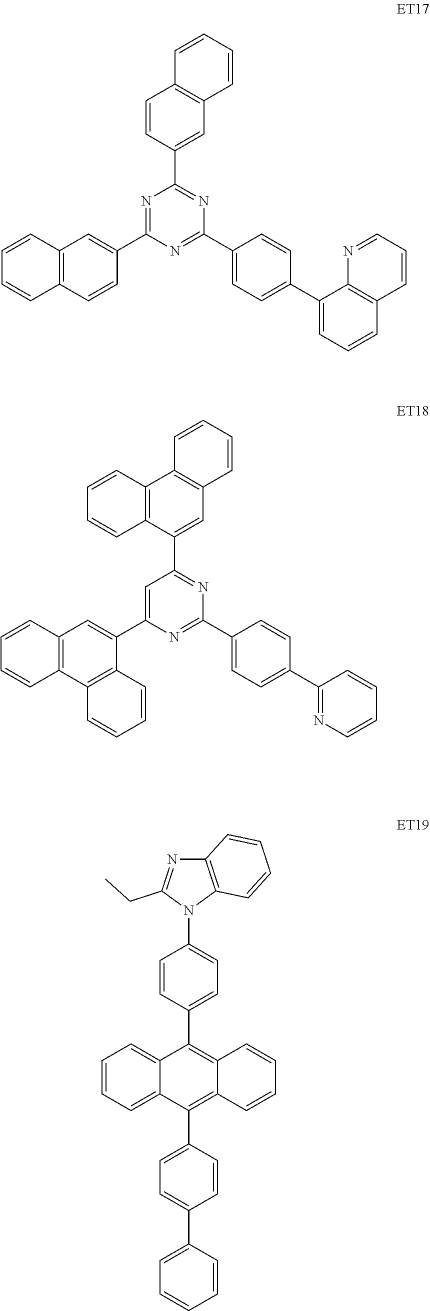 [SMILES: c1ccc2cc(-c3nc(-c4ccc(-c5cccc6cccnc56)cc4)nc(-c4ccc5ccccc5c4)n3)ccc2c1 ; c1ccc(-c2ccc(-c3nc(-c4cc5ccccc5c5ccccc45)cc(-c4cc5ccccc5c5ccccc45)n3)cc2)nc1 ; CCc1nc2ccccc2n1-c1ccc(-c2c3ccccc3c(-c3ccc(-c4ccccc4)cc3)c3ccccc23)cc1]

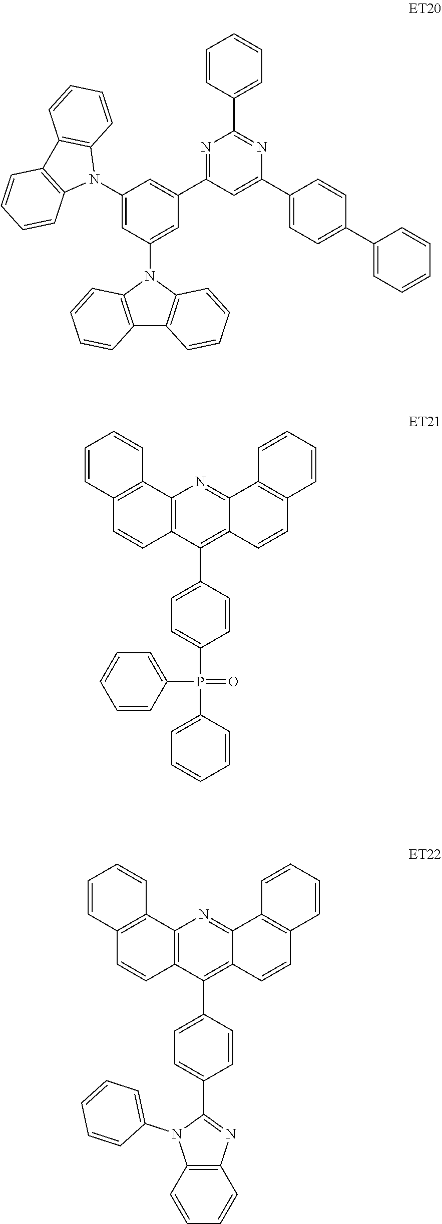 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; O=P(c1ccccc1)(c1ccccc1)c1ccc(-c2c3ccc4ccccc4c3nc3c2ccc2ccccc23)cc1 ; c1ccc(-n2c(-c3ccc(-c4c5ccc6ccccc6c5nc5c4ccc4ccccc45)cc3)nc3ccccc32)cc1]

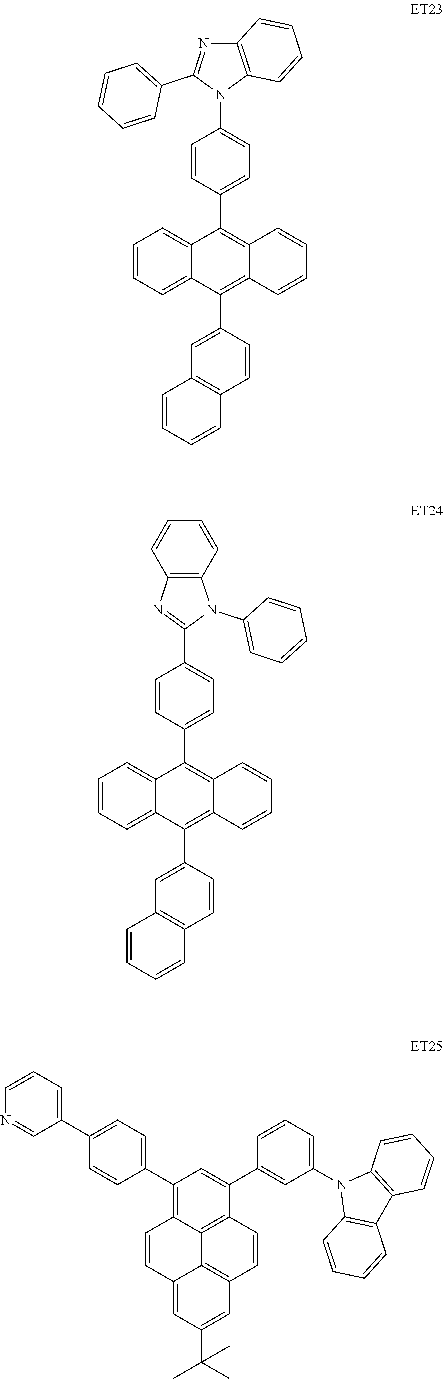 [SMILES: c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. When the thickness of the electron transport layer is within the range described above, satisfactory electron transport characteristics may be obtained without a substantial increase in driving voltage.

The electron transport layer may further include, in addition to the materials described above, a metal-containing material.

The metal-containing material may include a Li complex. The Li complex may include, for example, Compound ET-D1 (LiQ) or ET-D2:

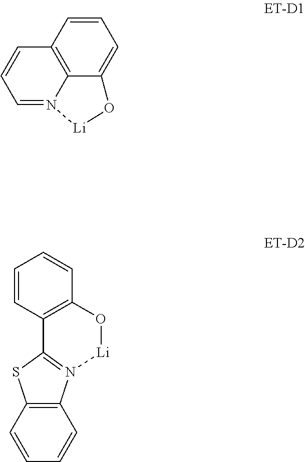

In addition, the electron transport region may include an electron injection layer to facilitate electron injection from the second electrode 19.

The electron injection layer may include LiF, NaCl, CsF, Li₂O, BaO, or a combination thereof.

A thickness of the electron injection layer may be in a range of about 1 Å to about 100 Å, for example, about 3 Å to about 90 Å. When the thickness of the electron injection layer is within the range described above, satisfactory electron injection characteristics may be obtained without a substantial increase in driving voltage.

The second electrode 19 may be disposed on the organic layer 15. The second electrode 19 may be a cathode. A material for forming the second electrode 19 may be a metal, an alloy, an electrically conductive compound, or a combination thereof, which has a relatively low work function. For example, the second electrode may comprise lithium (Li), magnesium (Mg), aluminum (Al), aluminum-lithium (Al—Li), calcium (Ca), magnesium-indium (Mg—In), magnesium-silver (Mg—Ag), or the like may be used as the material for forming the second electrode 19. In one or more embodiments, to obtain a top-emission light-emitting device, ITO or IZO may be used to form a transmissive second electrode 19, but embodiments are not limited thereto.

Hereinbefore, the organic light-emitting device according to one or more embodiments has been described in connection with the FIGURE, but embodiments of the present disclosure are not limited thereto.

According to an aspect of another embodiment, an electronic apparatus including the organic light-emitting device may be provided. The electronic apparatus may be used for various purposes such as a display, lighting, and a mobile phone.

Another aspect of the present disclosure provides a diagnostic composition including at least one organometallic compound represented by Formula 1.

The organometallic compound represented by Formula 1 may provide high luminance efficiency, and in this regard, the diagnostic composition including the organometallic compound may have high diagnostic efficiency.

The diagnostic composition may be variously applied to various kits, diagnostic reagents, biosensors, biomarkers, and the like.

The term “C₁-C₆₀ alkyl group” as used herein refers to a linear or branched saturated aliphatic hydrocarbon monovalent group having 1 to 60 carbon atoms. The term “C₁-C₆₀ alkylene group” as used herein refers to a divalent group having the same structure as the C₁-C₆₀ alkyl group.

Examples of the C₁-C₆₀ alkyl group, the C₁-C₂₀ alkyl group, and/or the C₁-C₁₀ alkyl group as used herein may include a methyl group, an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group or a tert-decyl group, each unsubstituted or substituted with a methyl group, an ethyl group, an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, or a combination thereof. In some embodiments, such as in Formula 9-33, the alkyl group may be a branched C₆ alkyl group. Formula 9-33 may be a tert-butyl group substituted with two methyl groups.

The term “C₁-C₆₀ alkoxy group” as used herein refers to a monovalent group represented by —OA₁₀₁ (wherein A₁₀₁ is a C₁-C₆₀ alkyl group). Examples of the C₁-C₆₀ alkoxy group, the C₁-C₂₀ alkoxy group, or the C₁-C₁₀ alkoxy group as used herein may include a methoxy group, an ethoxy group, a propoxy group, a butoxy group, or a pentoxy group.

The term “C₂-C₆₀ alkenyl group” as used herein refers to a group formed by placing at least one carbon-carbon double bond in the middle or at the terminus of the C₂-C₆₀ alkyl group. Examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a group formed by placing at least one carbon-carbon triple bond in the middle or at the terminus of the C₂-C₆₀ alkyl group. Examples thereof include an ethynyl group and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent cyclic saturated hydrocarbon group including 3 to 10 carbon atoms. The term “C₃-C₁₀ cycloalkylene group” as used herein refers to a divalent group having the same structure as the C₃-C₁₀ cycloalkyl group.

Examples of the C₃-C₁₀ cycloalkyl group as used herein may include a cyclopropyl group, a cyclobutyl group, a cyclopentyl group, a cyclohexyl group, a cycloheptyl group, a cyclooctyl group, an adamantanyl group, a norbornanyl group (a bicyclo[2.2.1]heptyl group), a bicyclo[1.1.1]pentyl group, a bicyclo[2.1.1]hexyl group, or a bicyclo[2.2.2]octyl group.

The term “C₁-C₁₀ heterocycloalkyl group” as used herein refers to a monovalent monocyclic group including at least one heteroatom selected from N, O, P, Si, Se, Ge, B, and S as a ring-forming atom and 1 to 10 carbon atoms. The term “C₁-C₁₀ heterocycloalkylene group” as used herein refers to a divalent group having the same structure as the C₁-C₁₀ heterocycloalkyl group.

Examples of the C₁-C₁₀ heterocycloalkyl group as used herein may include a silolanyl group, a silinanyl group, a tetrahydrofuranyl group, a tetrahydro-2H-pyranyl group, or a tetrahydrothiophenyl group.

The term “C₃-C₁₀ cycloalkenyl group” as used herein refers to a monovalent monocyclic group that has 3 to 10 carbon atoms and at least one carbon-carbon double bond in its ring, wherein the molecular structure as a whole is non-aromatic. Examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group including at least one heteroatom selected from N, O, P, Si, Se, Ge, B, and S as a ring-forming atom, 1 to 10 carbon atoms, and at least one double bond in its ring wherein the molecular structure as a whole is non-aromatic. Examples of the C₁-C₁₀ heterocycloalkenyl group include a 2,3-dihydrofuranyl group and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms. The term “C₆-C₆₀ arylene group” as used herein refers to a divalent group having a carbocyclic aromatic system having 6 to 60 carbon atoms. Examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include a plurality of rings, the plurality of rings may be fused to each other.

The term “C₇-C₆₀ alkylaryl group” as used herein refers to a C₆-C₆₀ aryl group substituted with at least one C₁-C₆₀ alkyl group.

The term “C₁-C₆₀ heteroaryl group” as used herein refers to a monovalent group having a heterocyclic aromatic system having at least one heteroatom selected from N, O, P, Si, Se, Ge, B, and S as a ring-forming atom and 1 to 60 carbon atoms. The term “C₁-C₆₀ heteroarylene group” as used herein refers to a divalent group having a heterocyclic aromatic system having at least one heteroatom selected from N, O, P, Si, Se, Ge, B, and S as a ring-forming atom and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include a plurality of rings, the plurality of rings may be fused to each other.

The term “C₂-C₆₀ alkylheteroaryl group” as used herein refers to a C₁-C₆₀ heteroaryl group substituted with at least one C₁-C₆₀ alkyl group.

The term “C₆-C₆₀ aryloxy group” as used herein is represented by —OA₁₀₂ (wherein A₁₀₂ is the C₆-C₆₀ aryl group). The term “C₆-C₆₀ arylthio group” as used herein is represented by —SA₁₀₃ (wherein A₁₀₃ is the C₆-C₆₀ aryl group). The term “C₁-C₆₀ alkylthio group” as used herein is represented by —SA₁₀₄ (wherein A₁₀₄ is the C₁-C₆₀ alkyl group).

The term “C₁-C₆₀ heteroaryloxy group” as used herein refers to —OA₁₀₆ (wherein A₁₀₆ is the C₂-C₆₀ heteroaryl group), the term “C₁-C₆₀ heteroarylthio group” as used herein indicates —SA₁₀₇ (wherein A₁₀₇ is the C₁-C₆₀ heteroaryl group), and the term “C₂-C₆₀ heteroarylalkyl group” as used herein refers to -A₁₀₈A₁₀₉ (A₁₀₉ is a C₁-C₅₉ heteroaryl group, and A₁₀₈ is a C₁-C₅₉ alkylene group).

The term “monovalent non-aromatic condensed polycyclic group” as used herein refers to a monovalent group that has two or more condensed rings and only carbon atoms (e.g., the number of carbon atoms may be in a range of 8 to 60) as ring-forming atoms, wherein the molecular structure as a whole is non-aromatic. Examples of the monovalent non-aromatic condensed polycyclic group include a fluorenyl group. The term “divalent non-aromatic condensed polycyclic group” as used herein refers to a divalent group having substantially the same structure as the monovalent non-aromatic condensed polycyclic group.

The term “monovalent non-aromatic condensed heteropolycyclic group” as used herein refers to a monovalent group that has two or more condensed rings and a heteroatom selected from N, O, P, Si, Se, Ge, B, and S and carbon atoms (e.g., the number of carbon atoms may be in a range of 1 to 60) as ring-forming atoms, wherein the molecular structure as a whole is non-aromatic. Examples of the monovalent non-aromatic condensed heteropolycyclic group include a carbazolyl group. The term “divalent non-aromatic condensed heteropolycyclic group” as used herein refers to a divalent group having substantially the same structure as the monovalent non-aromatic condensed heteropolycyclic group.

The term “C₅-C₃₀ carbocyclic group” as used herein refers to a saturated or unsaturated cyclic group including 5 to 30 carbon atoms as ring-forming atoms. The C₅-C₃₀ carbocyclic group may be a monocyclic group or a polycyclic group. Examples of the “C₅-C₃₀ carbocyclic group (unsubstituted or substituted with at least one R₁₀ₐ)” may include an adamantane group, a norbornene group, a norbornane group (a bicyclo[2.2.1]heptane group), a bicyclo[1.1.1]pentane group, a bicyclo[2.1.1]hexane group, a bicyclo[2.2.2]octane group, a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, or a fluorene group, each unsubstituted or substituted with at least one R₁₀ₐ as defined herein.

The term “C₁-C₃₀ heterocyclic group” as used herein refers to saturated or unsaturated cyclic group including 1 to 30 carbon atoms and at least one heteroatom selected from N, O, P, Si, Se, Ge, B, and S as ring-forming atoms. The C₁-C₃₀ heterocyclic group may be a monocyclic group or a polycyclic group. Examples of the “C₁-C₃₀ heterocyclic group (unsubstituted or substituted with at least one R₁₀ₐ)” may include a thiophene group, a furan group, a pyrrole group, a silole group, a borole group, a phosphole group, a selenophene group, a germole group, a benzothiophene group, a benzofuran group, an indole group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluorene-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group, each unsubstituted or substituted with at least one R₁₀ₐ as defined herein.

Examples of the terms “C₅-C₃₀ carbocyclic group” and “C₁-C₃₀ heterocyclic group” as used herein may include i) a first ring, ii) a second ring, iii) a condensed cyclic group in which two or more first rings are condensed with each other, iv) a condensed cyclic group in which two or more second rings are condensed with each other, or v) a condensed cyclic group in which at least one first ring is condensed with at least one second ring,
the first ring may be a cyclopentane group, a cyclopentadiene group, a furan group, a thiophene group, a pyrrole group, a silole group, a germole group, a borole group, a selenophene group, a phosphole group, an oxazole group, an oxadiazole group, an oxatriazole group, a thiazole group, a thiadiazole group, a thiatriazole group, a pyrazole group, an imidazole group, a triazole group, a tetrazole group, an azasilole group, an azagermole group, an azaborole group, an azaselenophene group, or an azaphosphole group, and
the second ring may be an adamantane group, a norbornane group (a bicyclo[2.2.1]heptane group), a norbornene group, a bicyclo[1.1.1]pentane group, a bicyclo[2.1.1]hexane group, a bicyclo[2.2.2]octane group, a cyclohexane group, a cyclohexene group, a benzene group, a pyridine group, a pyrimidine group, a pyrazine group, a pyridazine group, or a triazine group.

The “fluorinated C₁-C₆₀ alkyl group (or fluorinated C₁-C₂₀ alkyl group or the like)”, “fluorinated C₃-C₁₀ cycloalkyl group”, “fluorinated C₁-C₁₀ heterocycloalkyl group”, and “fluorinated phenyl group” as used herein may respectively be a C₁-C₆₀ alkyl group (or C₁-C₂₀ alkyl group or the like), C₃-C₁₀ cycloalkyl group, a C₁-C₁₀ heterocycloalkyl group, and a phenyl group, each substituted with at least one fluoro group (—F). Examples of the “fluorinated C₁ alkyl group (i.e., a fluorinated methyl group)” include —CF₃, —CF₂H, and —CFH₂. The “fluorinated C₁-C₆₀ alkyl group (or fluorinated C₁-C₂₀ alkyl group or the like)”, “fluorinated C₃-C₁₀ cycloalkyl group”, or “fluorinated C₁-C₁₀ heterocycloalkyl group” may respectively be: i) a fully fluorinated C₁-C₆₀ alkyl group (or fully fluorinated C₁-C₂₀ alkyl group or the like), fully fluorinated C₃-C₁₀ cycloalkyl group, or fully fluorinated C₁-C₁₀ heterocycloalkyl group, in which all hydrogen atoms are substituted with fluoro groups; or ii) a partially fluorinated C₁-C₆₀ alkyl group (or partially fluorinated C₁-C₂₀ alkyl group or the like), partially fluorinated C₃-C₁₀ cycloalkyl group, or partially fluorinated C₁-C₁₀ heterocycloalkyl group, in which one or more hydrogen atoms are substituted with fluoro groups.

The “deuterated C₁-C₆₀ alkyl group (or deuterated C₁-C₂₀ alkyl group or the like)”, “deuterated C₃-C₁₀ cycloalkyl group”, “deuterated C₁-C₁₀ heterocycloalkyl group”, and “deuterated phenyl group” as used herein may respectively be a C₁-C₆₀ alkyl group (or C₁-C₂₀ alkyl group or the like), C₃-C₁₀ cycloalkyl group, a C₁-C₁₀ heterocycloalkyl group, and a phenyl group, each substituted with at least one deuterium. Examples of the “deuterated C₁ alkyl group (i.e., a deuterated methyl group)” may include —CD₃, —CD₂H, and —CDH₂ and examples of the “deuterated C₃-C₁₀ cycloalkyl group” may refer to Formula 10-501 described in this disclosure. The “deuterated C₁-C₆₀ alkyl group (or deuterated C₁-C₂₀ alkyl group or the like)”, “deuterated C₃-C₁₀ cycloalkyl group”, or “deuterated C₁-C₁₀ heterocycloalkyl group” may respectively be: i) a fully deuterated C₁-C₆₀ alkyl group (or fully deuterated C₁-C₂₀ alkyl group or the like), fully deuterated C₃-C₁₀ cycloalkyl group, or fully deuterated C₁-C₁₀ heterocycloalkyl group, in which all hydrogen atoms are substituted with deuterium; or ii) a partially deuterated C₁-C₆₀ alkyl group (or partially deuterated C₁-C₂₀ alkyl group or the like), partially deuterated C₃-C₁₀ cycloalkyl group, or partially deuterated C₁-C₁₀ heterocycloalkyl group, in which one or more hydrogen atoms are substituted with deuterium(s).

The “(C₁-C₂₀ alkyl)‘X’ group” refers to a ‘X’ group substituted with at least one C₁-C₂₀ alkyl group. For example, the “(C₁-C₂₀ alkyl)C₃-C₁₀ cycloalkyl group” as used herein refers to a C₃-C₁₀ cycloalkyl group substituted with at least one C₁-C₂₀ alkyl group, and the “(C₁-C₂₀ alkyl)phenyl group” as used herein refers to a phenyl group substituted with at least one C₁-C₂₀ alkyl group. Examples of the (C₁ alkyl)phenyl group may include a toluyl group.

In the present specification, “an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, and an azadibenzothiophene 5,5-dioxide group” each refer to a heterocyclic ring in which at least one ring-forming carbon atom is substituted with a nitrogen atom and respectively having an identical backbone as “an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, and a dibenzothiophene 5,5-dioxide group”.

Substituents of the substituted C₅-C₃₀ carbocyclic group, the substituted C₁-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₇-C₆₀ alkyl aryl group, the substituted C₆-C₆₀ aryloxy group, the substituted C₆-C₆₀ arylthio group, the substituted C₇-C₆₀ arylalkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted C₂-C₆₀ alkylheteroaryl group, the substituted monovalent non-aromatic condensed polycyclic group, and the substituted monovalent non-aromatic condensed heteropolycyclic group may each independently be:
deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, C₁-C₆₀ alkoxy group, or C₁-C₆₀ alkylthio group each substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a C₂-C₆₀ alkylheteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ arylalkyl group, a C₁-C₆₀ heteroaryl group, a C₂-C₆₀ alkyl heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₇-C₆₀ alkyl aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a C₂-C₆₀ alkylheteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof.

In the present specification, Q₁ to Q₉, Q₁₁ to Q₁₉, Q₂₁ to Q₂₉, and Q₃₁ to Q₃₉ may each independently be: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, —F, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, —F, a C₁-C₆₀ alkyl group, a C₆-C₆₀ aryl group, or a combination thereof; a C₆-C₆₀ aryloxy group; a C₆-C₆₀ arylthio group; a C₇-C₆₀ arylalkyl group; a C₁-C₆₀ heteroaryl group; a C₁-C₆₀ heteroaryloxy group; a C₁-C₆₀ heteroarylthio group; a C₂-C₆₀ heteroarylalkyl group; a C₂-C₆₀ alkylheteroaryl group; a monovalent non-aromatic condensed polycyclic group; or a monovalent non-aromatic condensed heteropolycyclic group.

For example, Q₁ to Q₉, Q₁₁ to Q₁₉, Q₂₁ to Q₂₉, and Q₃₁ to Q₃₉ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, 3-pentyl group, a sec-isopentyl group, a phenyl group, a biphenyl group, or a naphthyl group, each unsubstituted or substituted with deuterium, a C₁-C₂₀ alkyl group, a phenyl group, or a combination thereof.

Hereinafter, a compound according to one or more exemplary embodiments and an organic light-emitting device according to one or more exemplary embodiments will be described in further detail with reference to Synthesis Examples and Examples, but the present disclosure is not limited to Synthesis Examples and Examples below. The expression “B was used instead of A” used in describing Synthesis Examples means that an identical number of molar equivalents of A was used in place of molar equivalents of B.

### EXAMPLES

### Synthesis Example 1 (Compound 15)

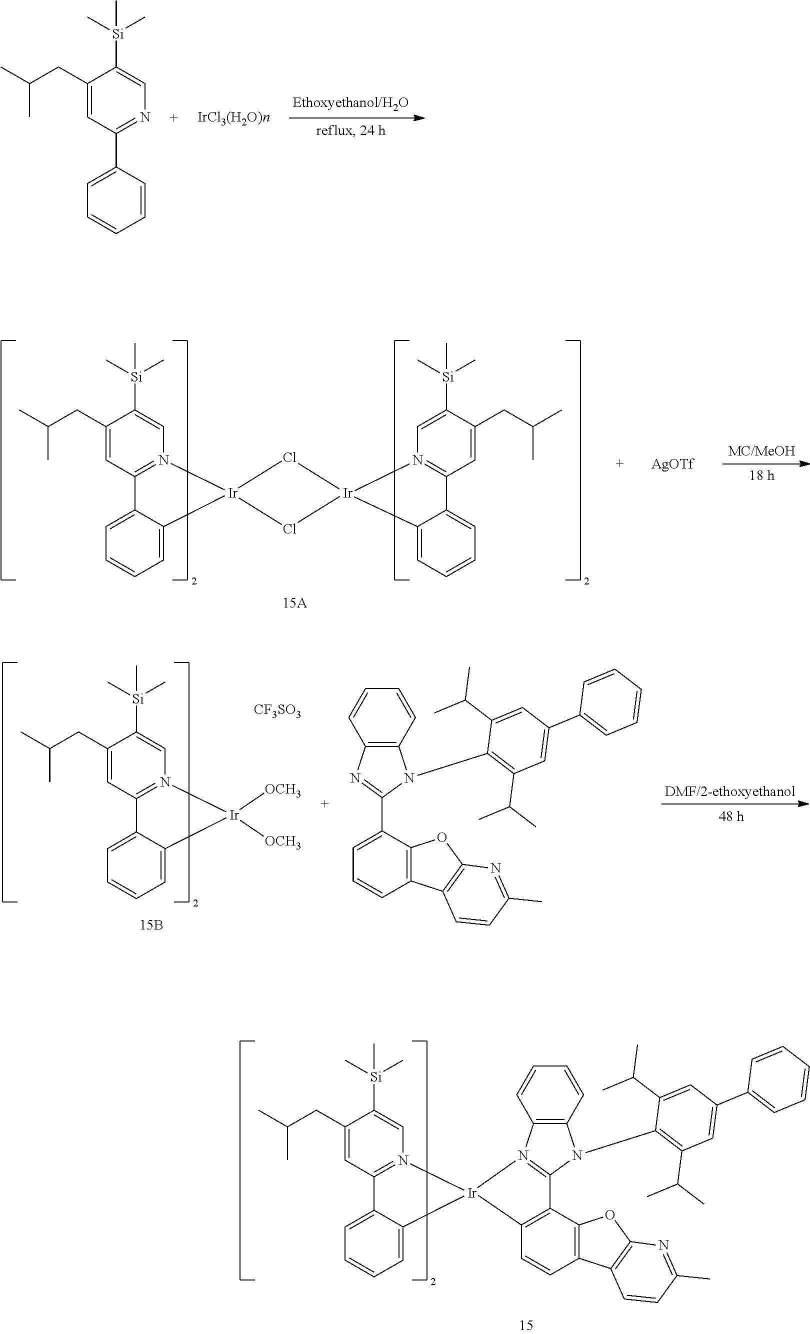

### Synthesis of Compound 15A

4-isobutyl-2-phenyl-5-(trimethylsilyl)pyridine (7.5 grams (g), 26.7 millimoles (mmol)) and iridium chloride (4.1 g, 11.9 mmol) were mixed with 120 milliliters (mL) of ethoxyethanol and 40 mL of deionized water, and then the mixture was stirred at reflux for 24 hours, and subsequently cooled to room temperature. A solid material formed therefrom was separated by filtration and washed thoroughly with water, methanol, and hexane in the stated order to obtain a solid which was then dried in a vacuum oven to obtain 7.43 g (yield of 79%) of Compound 15A.

### Synthesis of Compound 15B

After Compound 15A (3.0 g, 1.91 mmol) and 60 mL of methylene chloride were mixed, AgOTf (silver triflate, 0.98 g, 3.81 mmol) and 20 mL of methanol were mixed and added thereto. Subsequently, the mixture was stirred for 18 hours at room temperature while blocking light with aluminum foil, and then a resultant (Compound 15B) obtained by removing a solid generated by Celite filtration and decompressing a filtrate was used in the next reaction without additional purification.

### Synthesis of Compound 15

Compound 15B (3.68 g, 3.79 mmol) and 8-(1-(3,5-diisopropyl-[1,1′-biphenyl]-4-yl)-1H-benzo[d]imidazol-2-yl)-2-methylbenzofuro[2,3-b]pyridine) (2.24 g, 4.17 mmol) were mixed with 50 mL of 2-ethoxyethanol and 50 mL of dimethylformamide, and the mixture was stirred while refluxing for 48 hours at 130° C., and then the temperature was reduced to the room temperature. A compound obtained therefrom was decompressed to obtain a solid which was then subject to column chromatography using methylene chloride (MC):hexane to obtain 2.0 g (yield of 41%) of Compound 15. The material was identified by Mass spectrum and HPLC analysis.

High resolution mass spectrometry (HRMS) Matrix Assisted Laser Desorption Ionization (MALDI) calcd for C₇₃H₈₀IrN₅OSi₂: m/z 1291.5531. Found: 1291.5529.

### Synthesis Example 2 (Compound 295)

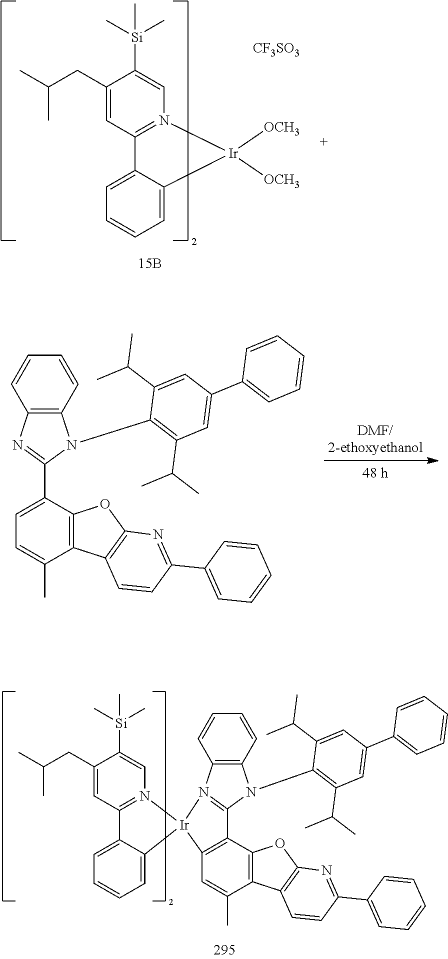

0.78 g (yield of 39%) of Compound 295 was obtained by using the same method as the synthesis method of Compound 15 of Synthesis Example 1, except that 8-(1-(3,5-diisopropyl-[1,1′-biphenyl]-4-yl)-1H-benzo[d]imidazol-2-yl)-5-methyl-2-phenylbenzofuro[2,3-b]pyridine was used instead of 8-(1-(3,5-diisopropyl-[1,1′-biphenyl]-4-yl)-1H-benzo[d]imidazol-2-yl)-2-methylbenzofuro[2,3-b]pyridine. The substance was identified by HRMS and HPLC analysis.

HRMS (MALDI) calcd for C₈₁H₈₈IrN₅OSi₂: m/z 1395.9863. Found: 1395.96.

### Synthesis Example 13 (Compound 184)

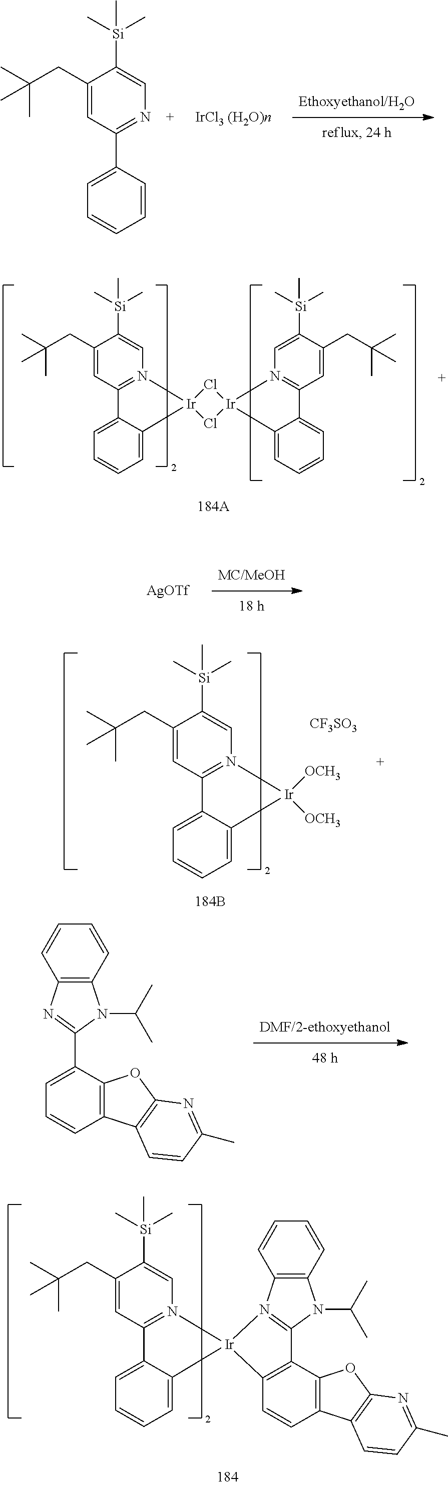

### Synthesis of Compound 184A

7.1 g (yield of 71%) of Compound 184A was obtained by using the same method as the synthesis method of Compound 15A of Synthesis Example 1, except that 4-neopentyl-2-phenyl-5-(trimethylsilyl)pyridine was used instead of 4-isopropyl-2-phenyl-5-(trimethylsilyl)pyridine.

### Synthesis of Compound 184B

Compound 184B was obtained by using the same method as the synthesis method of Compound 15B of Synthesis Example 1, except that Compound 184A was used instead of Compound 15A. The obtained Compound 184B was used in the next reaction without further purification.

### Synthesis of Compound 184

0.53 g (yield of 28%) of Compound 184 was obtained by using the same method as the synthesis method of Compound 15 of Synthesis Example 1, except that Compound 184B was used instead of Compound 15B, and 8-(1-isopropyl-1H-benzo[d]imidazol-2-yl)-2-methylbenzofuro[2,3-b]pyridine was used instead of 8-(1-(3,5-diisopropyl-[1,1′-biphenyl]-4-yl)-1H-benzo[d]imidazol-2-yl)-2-methylbenzofuro[2,3-b]pyridine. The substance was identified by HRMS and HPLC analysis.

HRMS (MALDI) calcd for C₆₀H₇₀IrN₅OSi₂: m/z 1125.4748. Found: 1125.4744.

### Synthesis Example 4 (Compound 212)

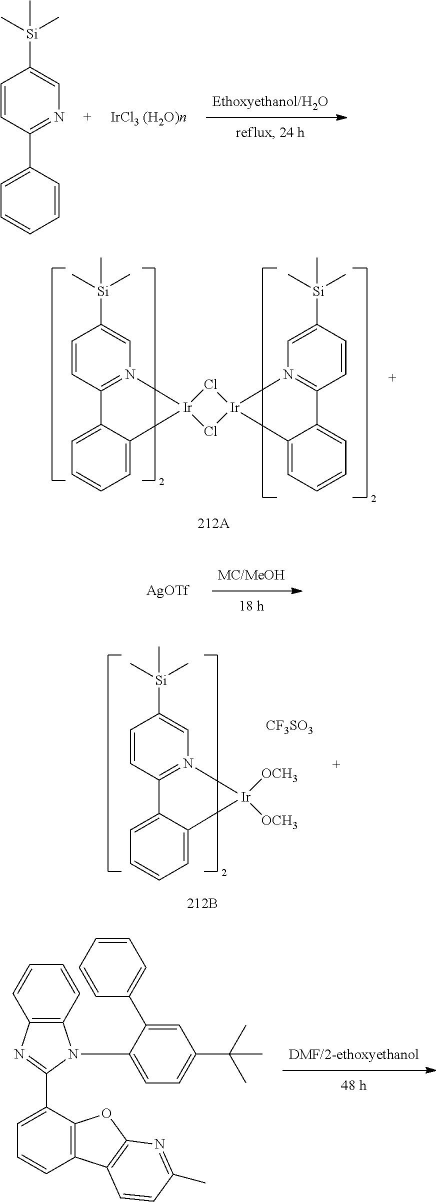

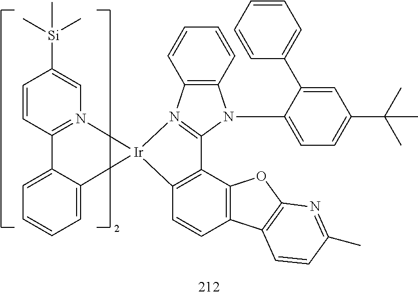

### Synthesis of Compound 212A

2-phenyl-5-(trimethylsilyl)pyridine (7.5 g, 33.1 mmol) and iridium chloride (5.2 g, 14.7 mmol) were mixed with 120 mL of ethoxyethanol and 40 mL of deionized water, and then the mixture was stirred while refluxing for 24 hours and cooled to room temperature. A solid material generated therefrom was separated by filtration and washed thoroughly with in the order of water/methanol/hexane to obtain a solid which was dried in a vacuum oven to obtain 8.2 g (yield of 82%) of Compound 212A.

### Synthesis of Compound 212B

After Compound 212A (1.6 g, 1.2 mmol) and 45 mL of methylene chloride were mixed, AgOTf (0.6 g, 2.3 mmol) and 15 mL of methanol were mixed and added thereto. Subsequently, the mixture was stirred for 18 hours at room temperature while blocking light with aluminum foil, and then a solid (Compound 212B) obtained by removing a solid generated by Celite filtration and decompressing a filtrate was used in the next reaction without additional purification.

### Synthesis of Compound 212

Compound 212B (1.49 g, 1.74 mmol) and 8(−(1-(5-(tert-butyl)-[1,1′-biphenyl]-2-yl)-1H-benzo[d]imidazol-2-yl)-2-methylbenzofuro[2,3-b]pyridine) (0.97 g, 1.91 mmol) were mixed with 20 mL of 2-ethoxyethanol and 20 mL of dimethylformamide, and the mixture was stirred while refluxing for 48 hours at 130° C., and then the temperature was lowered. A compound obtained therefrom was decompressed to obtain a solid which was then subjected to column chromatography using MC: hexane to obtain 0.73 g (yield of 37%) of Compound 212. The substance was identified by HRMS and HPLC analysis.

HRMS (MALDI) calcd for C₆₃H₆₀IrN₅OSi₂: m/z 1151.3699. Found: 1151.3698.

### Synthesis Example 5 (Compound 487)

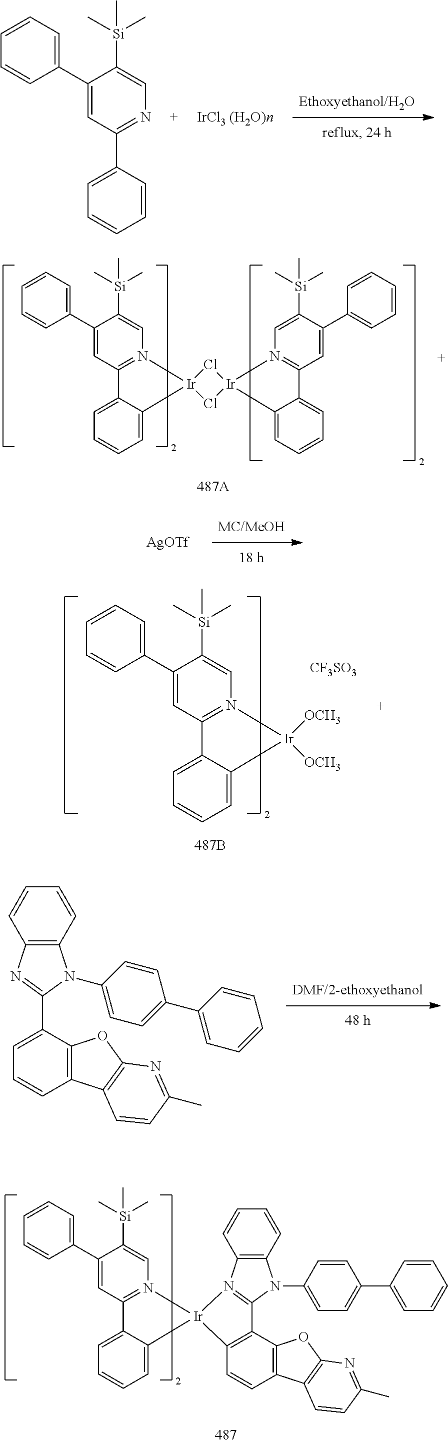

### Synthesis of Compound 487A

3.4 g (yield of 74%) of Compound 487A was obtained by using the same method as the synthesis method of Compound 212A of Synthesis Example 4, except that 2,4-diphenyl-5-(trimethylsilyl)pyridine was used instead of 2-phenyl-5-(trimethylsilyl)pyridine.

### Synthesis of Compound 487B

Compound 487B was obtained by using the same method as the synthesis method of Compound 212B of Synthesis Example 4, except that Compound 487A was used instead of Compound 212A. The obtained Compound 487B was used in the next reaction without further purification.

### Synthesis of Compound 487

0.84 g (yield of 42%) of Compound 487 was obtained by using the same method as the synthesis method of Compound 212 of Synthesis Example 4, except that Compound 487B was used instead of Compound 212B and 8-(1-([1,1′-biphenyl]-4-yl)-1H-benzo[d]imidazol-2-yl)-2-methylbenzofuro[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₇₁H₆₀IrN₅OSi₂: m/z 1247.6570. Found: 1247.6571.

### Synthesis Example 6 (Compound 982)

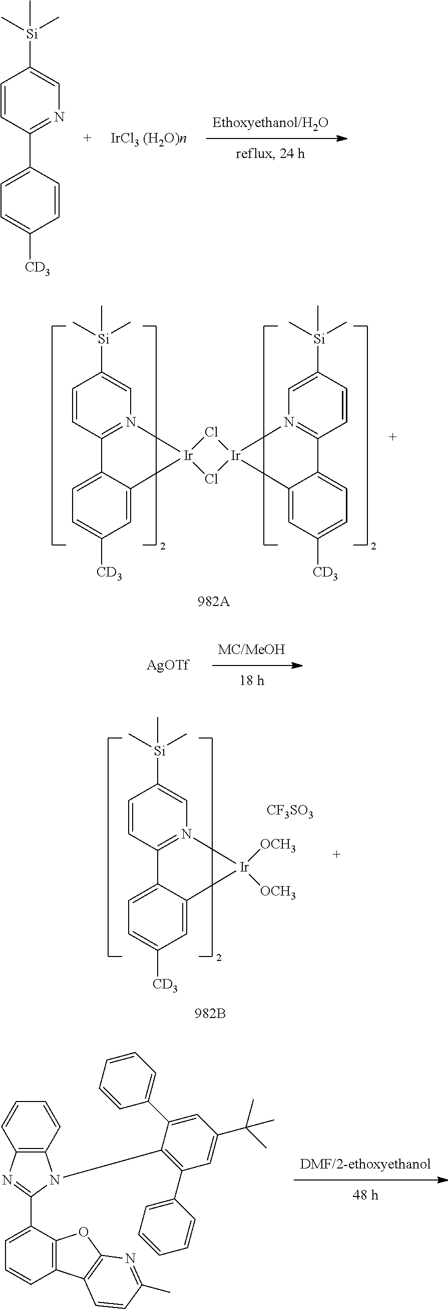

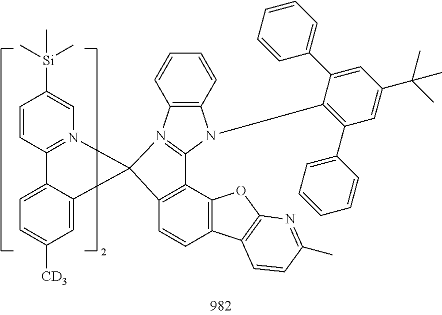

### Synthesis of Compound 982A

5.3 g (yield of 79%) of Compound 982A was obtained by using the same method as the synthesis method of Compound 212A of Synthesis Example 4, except that (2-(p-tolyl-D₃)-5-(trimethylsilyl)pyridine) was used instead of 2-phenyl-5-(trimethylsilyl)pyridine.

### Synthesis of Compound 982B

Compound 982B was obtained by using the same method as the synthesis method of Compound 212B of Synthesis Example 4, except that Compound 982A was used instead of Compound 212A. The obtained Compound 982B was used in the next reaction without further purification.

### Synthesis of Compound 982

0.78 g (yield of 39%) of Compound 982 was obtained by using the same method as the synthesis method of Compound 212 of Synthesis Example 4, except that Compound 982B was used instead of Compound 212B and 8-(1-(5′-(tert-butyl)-[1,1′:3′,1″-terphenyl]-2′-yl)-1H-benzo[d]imidazol-2-yl)-2-methylbenzofuro[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₇₁H₆₂D₆IrN₅OSi₂: m/z 1261.4968. Found: 1261.4956.

### Synthesis Example 7 (Compound 1042)

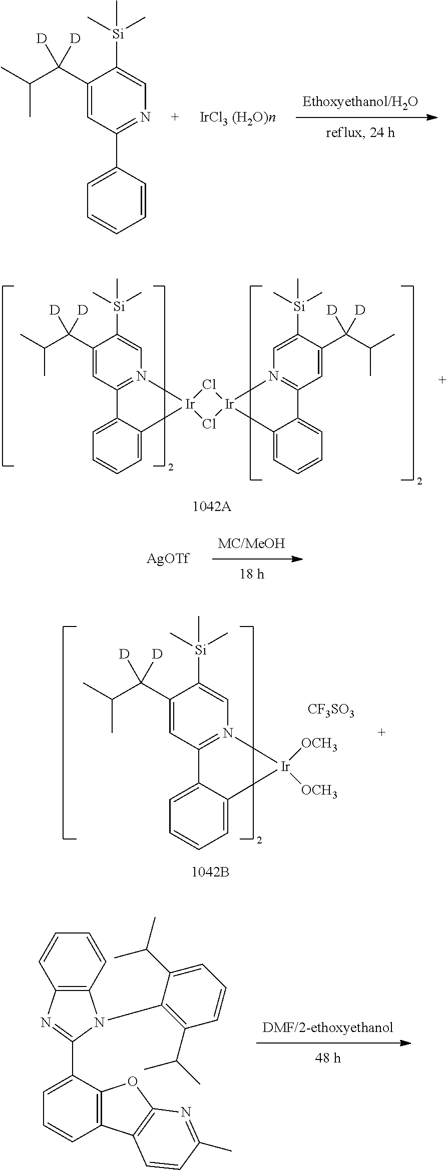

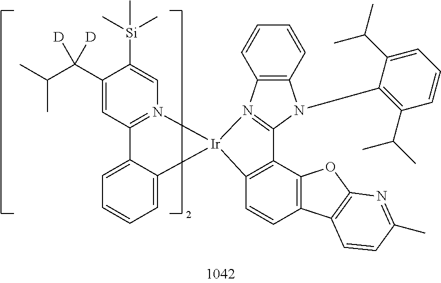

### Synthesis of Compound 1042A

2.5 g (yield of 68%) of Compound 1042A was obtained by using the same method as the synthesis method of Compound 212A of Synthesis Example 4, except that 4-isobutyl(D₂)-2-phenyl-5-(trimethylsilyl)pyridine was used instead of 2-phenyl-5-(trimethylsilyl)pyridine.

### Synthesis of Compound 1042B

Compound 1042B was obtained by using the same method as the synthesis method of Compound 212B of Synthesis Example 4, except that Compound 1042A was used instead of Compound 212A. The obtained Compound 1042B was used in the next reaction without further purification.

### Synthesis of Compound 1042

0.49 g (yield of 33%) of Compound 1042 was obtained by using the same method as the synthesis method of Compound 212 of Synthesis Example 4, except that Compound 1042B was used instead of Compound 212B and 8-(1-(2,6-diisopropylphenyl)-1H-benzo[d]imidazol-2-yl)-2-methylbenzofuro[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS(MALDI) calcd for C₆₇H₇₁D₄IrN₄OSi₂: m/z 1204.5360. Found: 1204.5364.

### Synthesis Example 8 (Compound 1229)

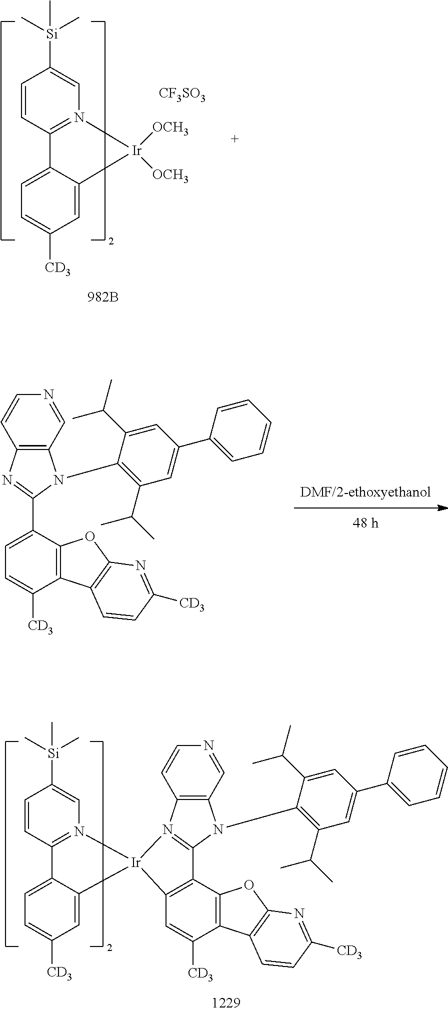

### Synthesis of Compound 1229

0.35 g of (yield of 23%) of Compound 1229 was obtained by using the same method as the synthesis method of Compound 212 of Synthesis Example 4, except that Compound 982B was used instead of Compound 212B and 8-(3-(3,5-diisopropyl-[1,1′-biphenyl]-4-yl)-3H-imidazo[4,5-c]pyridin-2-yl)-2,5-dimethyl(D₆)benzofuro[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₆₈H₅₈D₁₂IrN₆OSi₂: m/z 1234.5454. Found: 1234.5450.

### Synthesis Example 9 (Compound 1550)

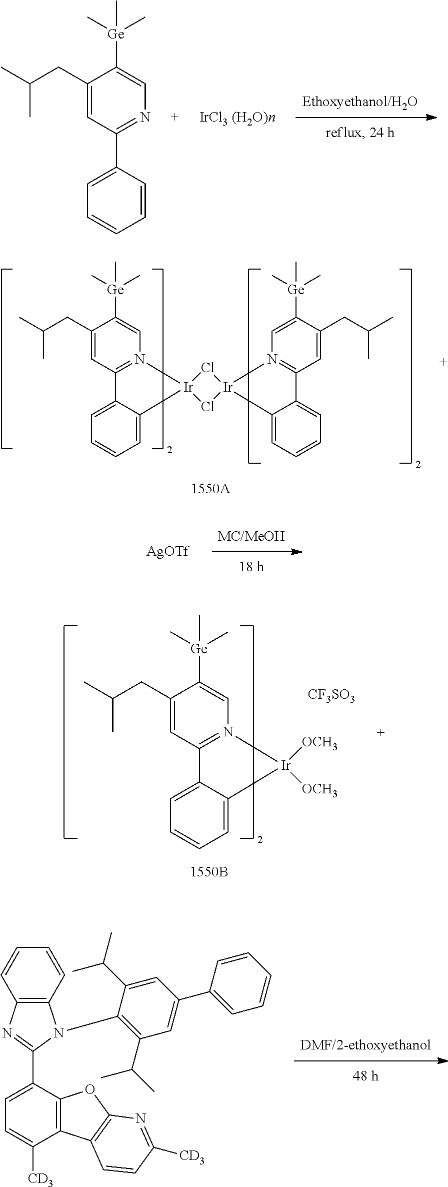

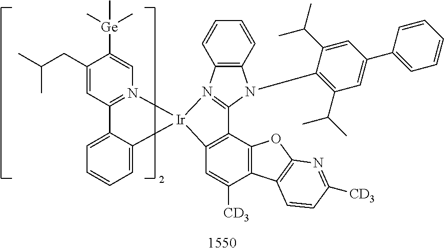

### Synthesis of Compound 1550A

3.3 g (yield of 65%) of Compound 1550A was obtained by using the same method as the synthesis method of Compound 15A of Synthesis Example 1, except that 4-isobutyl-2-phenyl-5-(trimethylgermyl)pyridine was used instead of 4-isobutyl-2-phenyl-5-(trimethylsilyl)pyridine.

### Synthesis of Compound 1550B

Compound 1550B was obtained by using the same method as the synthesis method of Compound 15B of Synthesis Example 1, except that Compound 1550A was used instead of Compound 15A. The obtained Compound 1550B was used in the next reaction without further purification.

### Synthesis of Compound 1550

0.56 g (yield of 28%) of Compound 1550 was obtained by using the same method as the synthesis method of Compound 15 of Synthesis Example 1, except that Compound 1550B was used instead of Compound 15B and (8-(1-(3,5-diisopropyl-[1,1′-biphenyl]-4-yl)-1H-benzo[d]imidazol-2-yl)-2,5-dimethyl(D₆)benzofuro[2,3-b]pyridine) was used instead of 8-(1-(3,5-diisopropyl-[1,1′-biphenyl]-4-yl)-1H-benzo[d]imidazol-2-yl)-2-methylbenzofuro[2,3-b]pyridine. The substance was identified by HRMS and HPLC analysis.

HRMS (MALDI) calcd for C₇₄H₇₆D₆Ge₂IrN₅O: m/z 1403.4949. Found: 1403.4946.

### Synthesis Example 10 (Compound 1725)

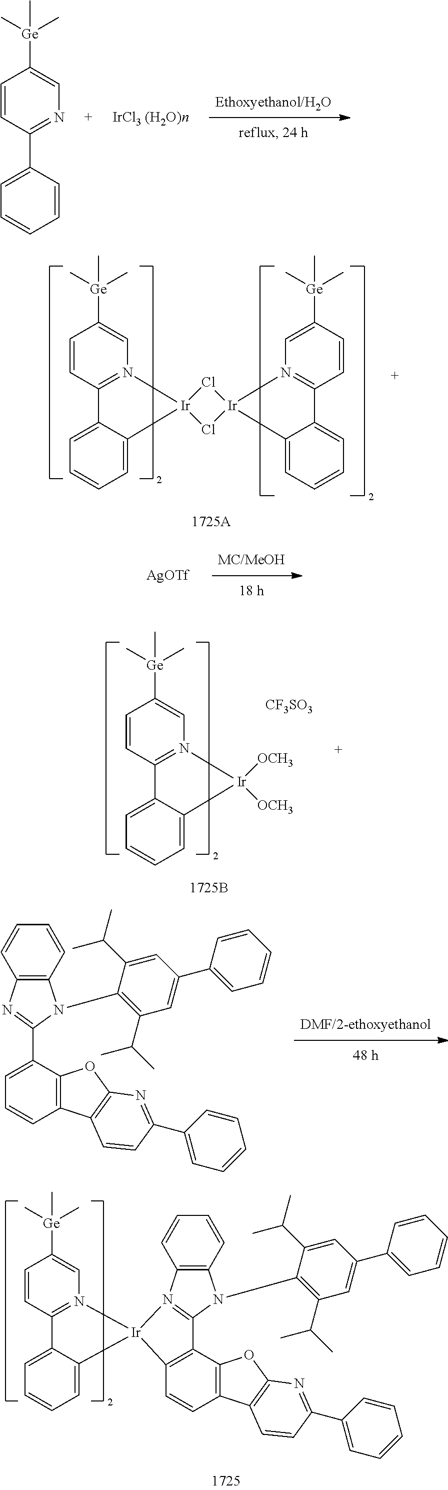

### Synthesis of Compound 1725A

2.1 g (yield of 61%) of Compound 1725A was obtained by using the same method as the synthesis method of Compound 212A of Synthesis Example 4, except that 2-phenyl-5-(trimethylgermyl)pyridine was used instead of 2-phenyl-5-(trimethylsilyl)pyridine.

### Synthesis of Compound 1725B

Compound 1725B was obtained by using the same method as the synthesis method of Compound 212B of Synthesis Example 4, except that Compound 1725A was used instead of Compound 212A. The obtained Compound 1725B was used in the next reaction without further purification.

### Synthesis of Compound 1725

0.76 g (yield of 38%) of Compound 1725 was obtained by using the same method as the synthesis method of Compound 212 of Synthesis Example 4, except that Compound 1725B was used instead of Compound 212B and 8-(1-(3,5-diisopropyl-[1,1′-biphenyl]-4-yl)-1H-benzo[d]imidazol-2-yl)-2-phenylbenzofuro[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₇₀H₆₆Ge₂IrN₅O: m/z 1333.3320. Found: 1333.3318.

### Synthesis Example 11 (COMPOUND 2610)

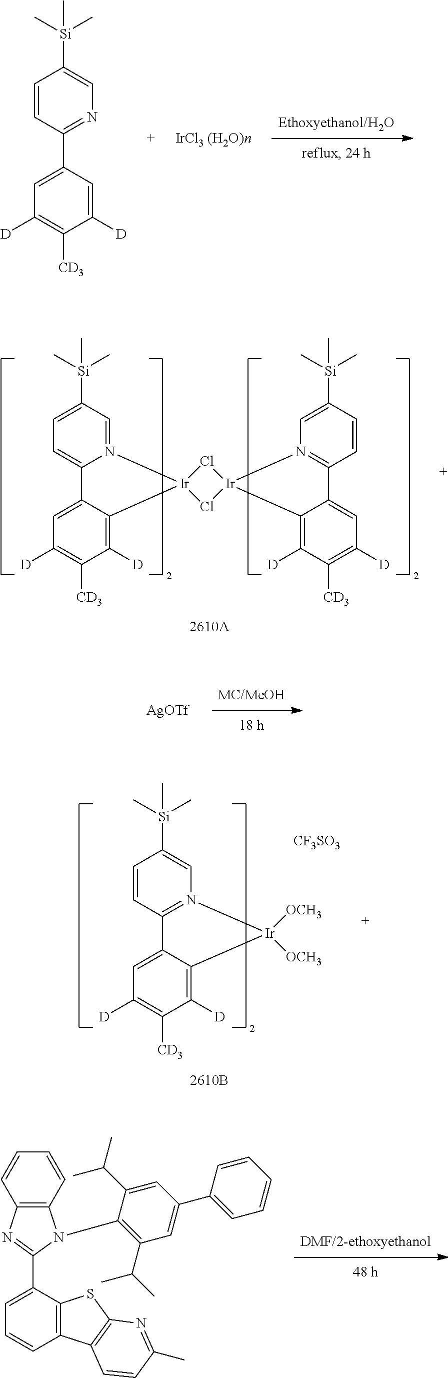

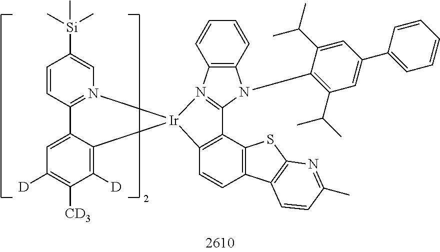

### Synthesis of Compound 2610A

2.4 g (yield of 64%) of Compound 2610A was obtained by using the same method as the synthesis method of Compound 212A of Synthesis Example 4, except that 2-(p-tolyl-D₅)-5-(trimethylsilyl)pyridine was used instead of 2-phenyl-5-(trimethylsilyl)pyridine.

### Synthesis of Compound 2610B

Compound 2610B was obtained by using the same method as the synthesis method of Compound 212B of Synthesis Example 4, except that Compound 2610A was used instead of Compound 212A. The obtained Compound 2610B was used in the next reaction without further purification.

### Synthesis of Compound 2610

0.73 g (yield of 37%) of Compound 2610 was obtained by using the same method of the synthesis method of Compound 212 of Synthesis Example 4, except that Compound 2610B was used instead of Compound 212B and 8-(1-(3,5-diisopropyl-[1,1′-biphenyl]-4-yl)-1H-benzo[d]imidazol-2-yl)-2-methylbenzo[4,5]thieno[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₆₇H₅₈D₁₀IrN₅SSi₂: m/z 1233.4991. Found: 1233.4988.

### Synthesis Example 12 (Compound 2755)

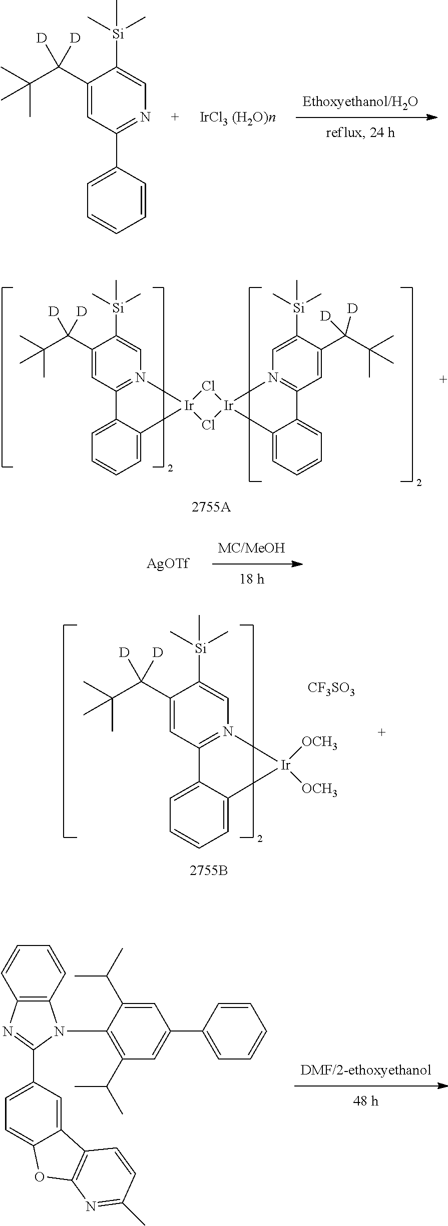

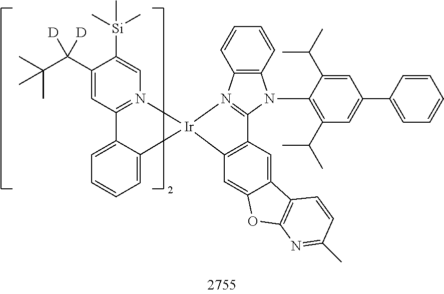

### Synthesis of Compound 2755A

4.2 g (yield of 81%) of Compound 2755A was obtained by using the same method as the synthesis method of Compound 212A of Synthesis Example 4, except that 4-neopentyl(D₂)-2-phenyl-5-(trimethylsilyl)pyridine was used instead of 2-phenyl-5-(trimethylsilyl)pyridine.

### Synthesis of Compound 2755B

Compound 2755B was obtained by using the same method as the synthesis method of Compound 212B of Synthesis Example 4, except that Compound 2755A was used instead of Compound 212A. The obtained Compound 2755B was used in the next reaction without further purification.

### Synthesis of Compound 2755

0.65 g (yield of 33%) of Compound 2755 was obtained by using the same method as the synthesis method of Compound 212 of Synthesis Example 4, except that Compound 2755B was used instead of Compound 212B and 6-(1-(3,5-diisopropyl-[1,1′-biphenyl]-4-yl)-1H-benzo[d]imidazol-2-yl)-2-methylbenzofuro[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₇₅H₈₀IrN₅OSi₂: m/z 1323.6095. Found: 1323.6090.

### Synthesis Example 13 (Compound 3214)

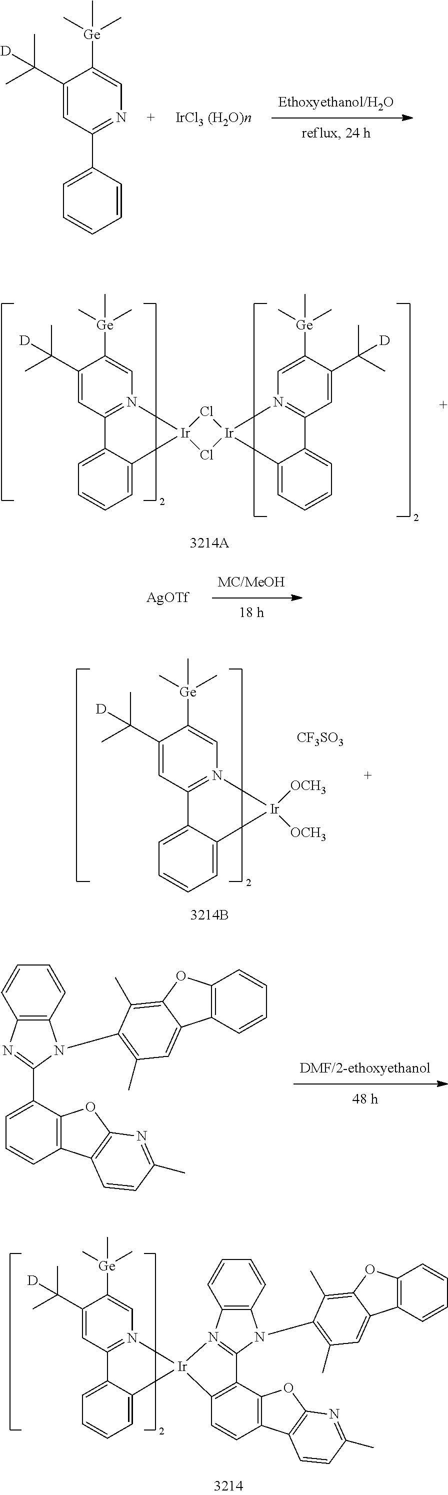

### Synthesis of Compound 3214A

8.0 g (yield of 80%) of Compound 3214A was obtained by using the same method as the synthesis method of Compound 212A of Synthesis Example 4, except that 2-phenyl-4-(propan-2-yl-2-D)-5-(trimethylgermyl)pyridine was used instead of 2-phenyl-5-(trimethylsilyl)pyridine.

### Synthesis of Compound 3214B

Compound 3214B was obtained by using the same method as the synthesis method of Compound 212B of Synthesis Example 4, except that Compound 3214A was used instead of Compound 212A. The obtained Compound 3214B was used in the next reaction without further purification.

### Synthesis of Compound 3214

0.76 g (yield of 38%) of Compound 3214 was obtained by using the same method as the synthesis method of Compound 212 of Synthesis Example 4, except that Compound 3214B was used instead of Compound 212B and 8-(1-(2,4-dimethyldibenzo[b,d]furan-3-yl)-1H-benzo[d]imidazol-2-yl)-2-methylbenzofuro[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₆₇H₆₄D₂Ge₂N₅O₂: m/z 1315.3395. Found: 1315.3394.

### Synthesis Example 14 (Compound 3275)

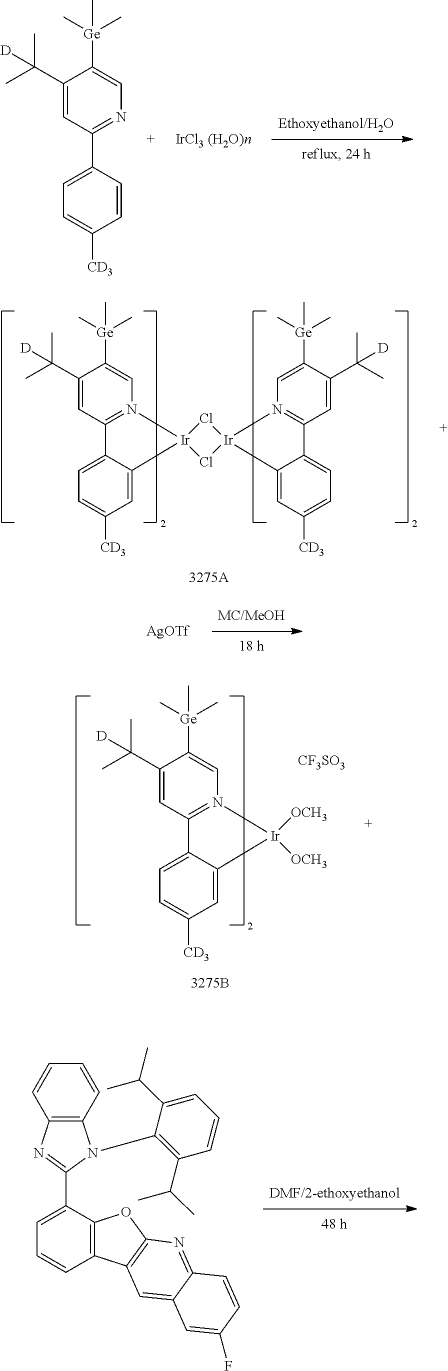

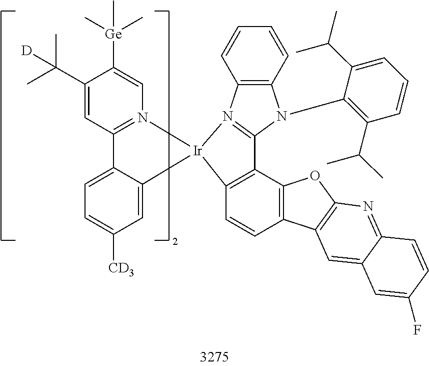

### Synthesis of Compound 3275A

8.5 g (yield of 71%) of Compound 3275A was obtained by using the same method as the synthesis method of Compound 212A of Synthesis Example 4, except that 2-(4-(methyl-d3)phenyl)-4-(propan-2-yl-2-d)-5-(trimethylgermyl)pyridine was used instead of 2-phenyl-5-(trimethylsilyl)pyridine.

### Synthesis of Compound 3275B

Compound 3275B was obtained by using the same method as the synthesis method of Compound 212B of Synthesis Example 4, except that Compound 3275A was used instead of Compound 212A. The obtained Compound 3275B was used in the next reaction without further purification.

### Synthesis of Compound 3275

0.61 g (yield of 34%) of Compound 3275 was obtained by using the same method as the synthesis method of Compound 212 of Synthesis Example 4, except that Compound 3275B was used instead of Compound 212B and 4-(1-(2,6-diisopropylphenyl)-1H-benzo[d]imidazol-2-yl)-9-fluorobenzofuro[2,3-b]quinolone was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₇₀H₆₇D₈FGe₂IrN₅O: m/z 1369.4511. Found: 1369.4509.

### Synthesis Example 15 (Compound 3492)

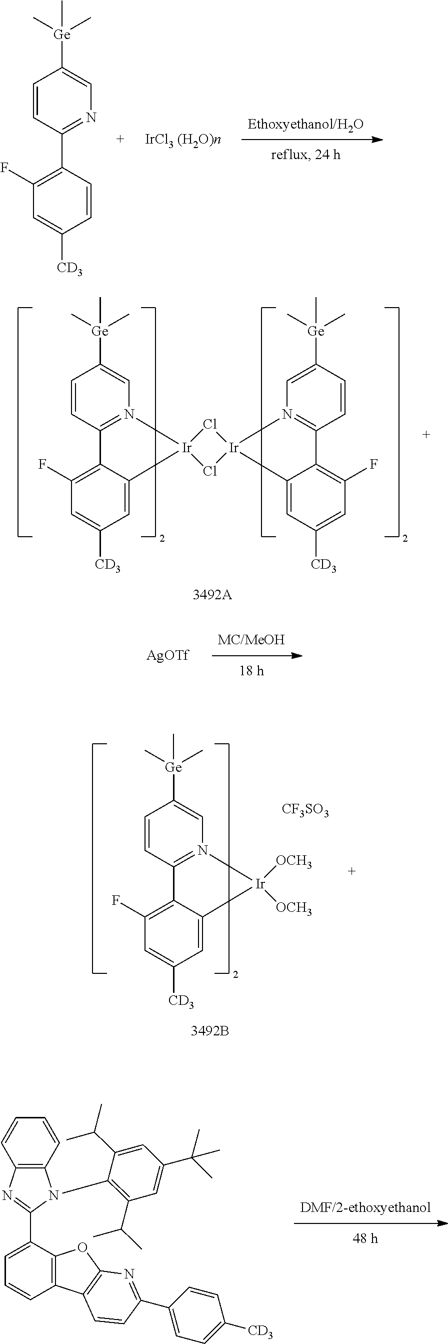

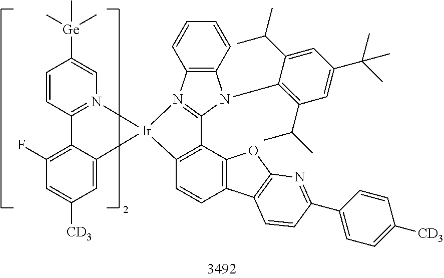

### Synthesis of Compound 3492A

9.0 g (yield of 75%) of Compound 3492A was obtained by using the same method as the synthesis method of Compound 212A of Synthesis Example 4, except that 2-(2-fluoro-4-(methyl-d3)phenyl)-5-(trimethylgermyl)pyridine was used instead of 2-phenyl-5-(trimethylsilyl)pyridine.

### Synthesis of Compound 3492B

Compound 3492B was obtained by using the same method as the synthesis method of Compound 212B of Synthesis Example 4, except that Compound 3492A was used instead of Compound 212A. The obtained Compound 3492B was used in the next reaction without further purification.

### Synthesis of Compound 3492

0.59 g (yield of 35%) of Compound 3492 was obtained by using the same method as the synthesis method of Compound 212 of Synthesis Example 4, except that Compound 3492B was used instead of Compound 212B and 8-(1-(4-(tert-butyl)-2,6-diisopropylphenyl)-1H-benzo[d]imidazol-2-yl)-2-(4-(methyl-d3)phenyl)benzofuro[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₇₁H₆₅D₉F₂Ge₂IrN₅O: m/z 1400.4479. Found: 1400.4477.

### Synthesis Example 16 (Compound 3553)

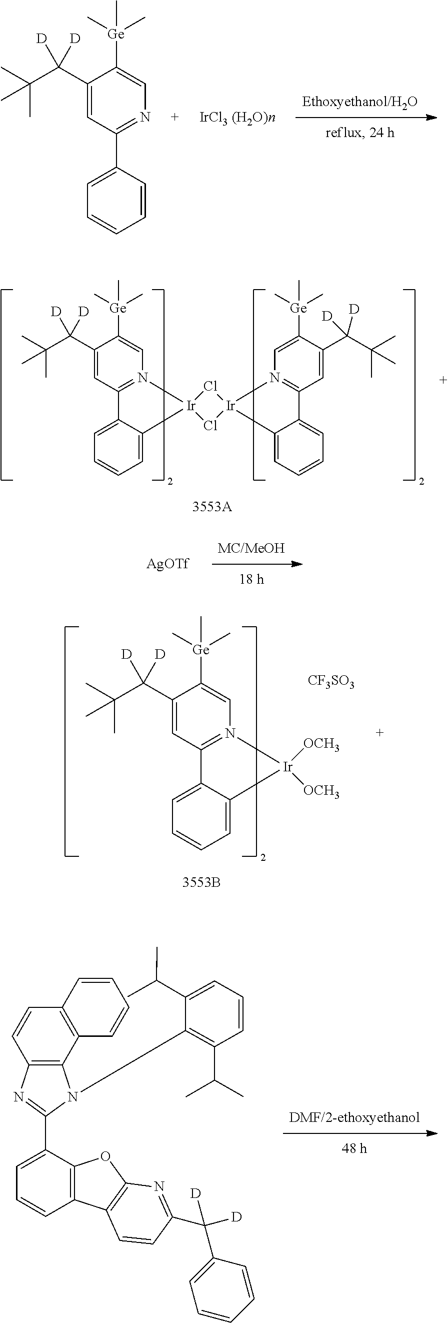

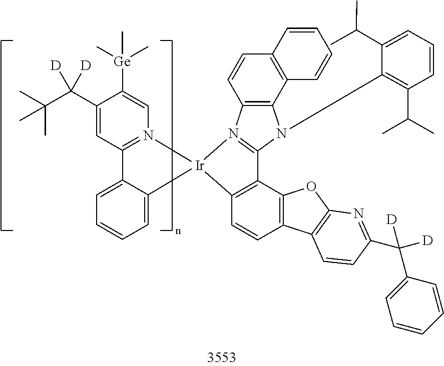

### Synthesis of Compound 3553A

8.5 g (yield of 77%) of Compound 3553A was obtained by using the same method as the synthesis method of Compound 212A of Synthesis Example 4, except that 4-(2,2-dimethylpropyl-1,1-d2)-2-phenyl-5-(trimethylgermyl)pyridine was used instead of 2-phenyl-5-(trimethylsilyl)pyridine.

### Synthesis of Compound 3553B

Compound 3553B was obtained by using the same method as the synthesis method of Compound 212B of Synthesis Example 4, except that Compound 3553A was used instead of Compound 212A. The obtained Compound 3553B was used in the next reaction without further purification.

### Synthesis of Compound 3553

0.55 g (yield of 32%) of Compound 3553 was obtained by using the same method as the synthesis method of Compound 212 of Synthesis Example 4, except that Compound 3553B was used instead of Compound 212B and 8-(1-(2,6-diisopropylphenyl)-1H-naphtho[1,2-d]imidazol-2-yl)-2-(phenylmethyl-d₂)benzofuro[2,3-b]pyridine was used instead of 8(−(1-(5-(tert-butyl)-[1,1′-biphenyl]-2-yl)-1H-benzo[d]imidazol-2-yl)-2-methylbenzofuro[2,3-b]pyridine. The substance was identified by HRMS and HPLC analysis.

HRMS (MALDI) calcd for C₇₉H₈₀D₆Ge₂IrN₅O: m/z 1467.5262. Found: 1467.5260.

### Example 1

As an anode, a glass substrate with ITO patterned thereon was cut to a size of 50 mm×50 mm×0.5 mm, sonicated by using isopropyl alcohol and deionized water for 5 minutes each, and then irradiated with ultraviolet (UV) light for 30 minutes and exposed to ozone for cleaning. Then, the resultant glass substrate was loaded onto a vacuum deposition apparatus.

Compound HT3 and F6-TCNNQ were vacuum deposited at a weight ratio of 98:2 on the anode to form a hole injection layer having a thickness of 100 Å, and Compound HT3 was vacuum deposited on the hole injection layer to form a hole transport layer having a thickness of 1650 Å.

Subsequently, Compound CBP (host) and Compound 15 (dopant) were co-deposited at a weight ratio of 95:5 on the hole transport layer to form an emission layer having a thickness of 400 Å.

Thereafter, Compound ET3 and ET-D1 were co-deposited at a volume ratio of 50:50 on the emission layer to form an electron transport layer having a thickness of 350 Å, ET-D1 was vacuum deposited on the electron transport layer to form an electron injection layer having a thickness of 10 Å, and Al was vacuum deposited on the electron injection layer to form a cathode having a thickness of 1000 Å, and thereby an organic light-emitting device was manufactured.

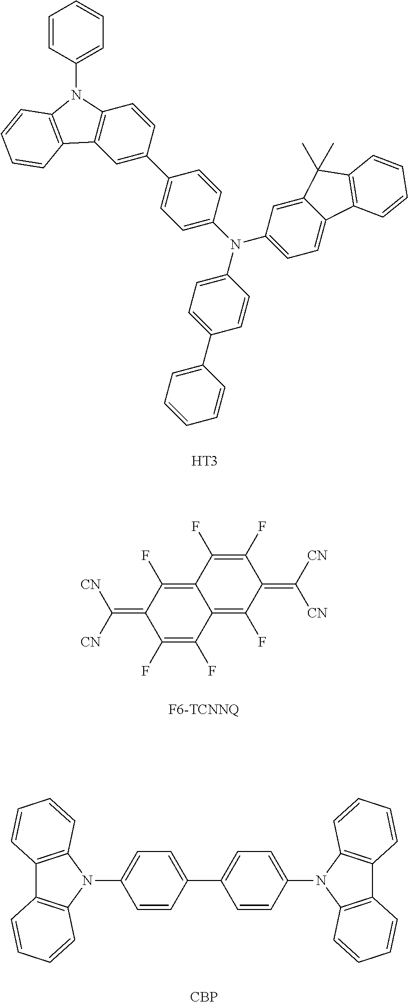

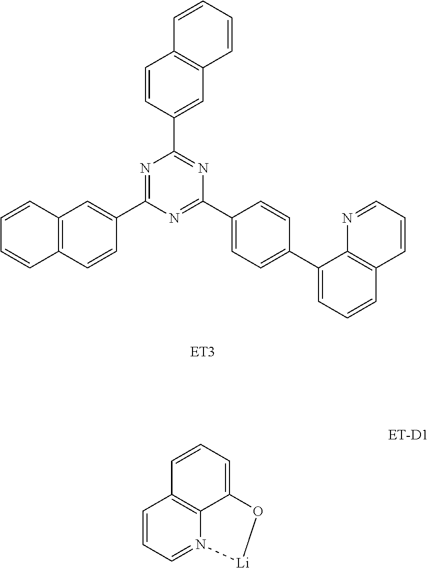

### Examples 2 to 15 and Comparative Examples A to C

Organic light-emitting devices were manufactured in the same manner as in Example 1, except that in forming an emission layer, for use as a dopant, corresponding compounds shown in Table 2 were used instead of Compound 15.

### Evaluation Example 1

For each organic light-emitting device manufactured in Examples 1 to 15 and Comparative Examples A to C, the maximum value of external quantum efficiency (Max EQE), roll-off ratio, and lifespan (LT₉₇) were evaluated. The results are shown in Table 2. This evaluation was performed using a current-voltage meter (Keithley 2400) and a luminescence meter (Minolta Cs-1,000A), and the lifespan (LT₉₇) (at 9000 candela per square meter, Cd/m²) was expressed as a relative value (%) by evaluating the time (hours, hr) for the luminance of 97% with respect to the initial luminance of 100%. The roll-off ratio was calculated by the following equation 20.

Roll-off ratio={1−(efficiency (at 9000 Cd/m²)/maximum luminescent efficiency)}×100% Equation 20

TABLE 2

| | Dopant in | | | LT₉₇ (a |
|---|---|---|---|---|
| | emission | | | relative |
| | layer | | Roll-off | value, %) |
| | (Compound | Max EQE | ratio | (at 9000 |
| | No.) | (%) | (%) | cd/m²) |
| Example 1 | 15 | 27.6 | 10 | 134 |
| Example 2 | 184 | 25.6 | 16 | 100 |
| Example 3 | 212 | 27.1 | 11 | 156 |
| Example 4 | 295 | 26.5 | 12 | 114 |
| Example 5 | 982 | 25.6 | 14 | 106 |
| Example 6 | 1042 | 27.2 | 15 | 98 |
| Example 7 | 1229 | 24.7 | 14 | 99 |
| Example 8 | 1550 | 25.1 | 15 | 100 |
| Example 9 | 1725 | 27.5 | 12 | 145 |
| Example 10 | 2610 | 28.0 | 11 | 172 |
| Example 11 | 2755 | 24.5 | 10 | 138 |
| Example 12 | 3214 | 27.4 | 12 | 130 |
| Example 13 | 3275 | 27.1 | 13 | 210 |
| Example 14 | 3492 | 27.8 | 10 | 102 |
| Example 15 | 3553 | 27.1 | 14 | 125 |
| Comparative | A | 23.2 | 20 | 50 |
| Example A | | | | |
| Comparative | B | 20.9 | 28 | 42 |
| Example B | | | | |
| Comparative | C | 19.6 | 25 | 30 |
| Example C | | | | |

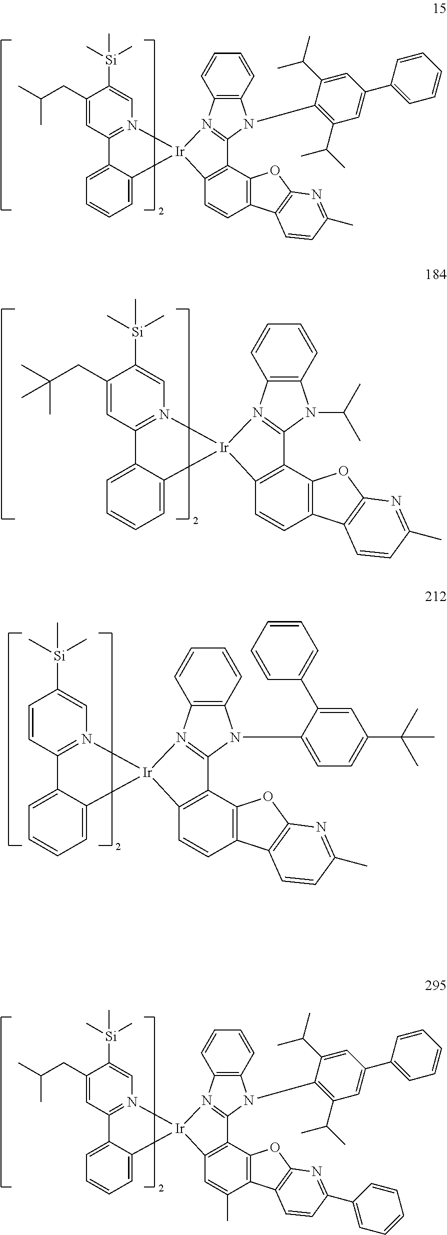

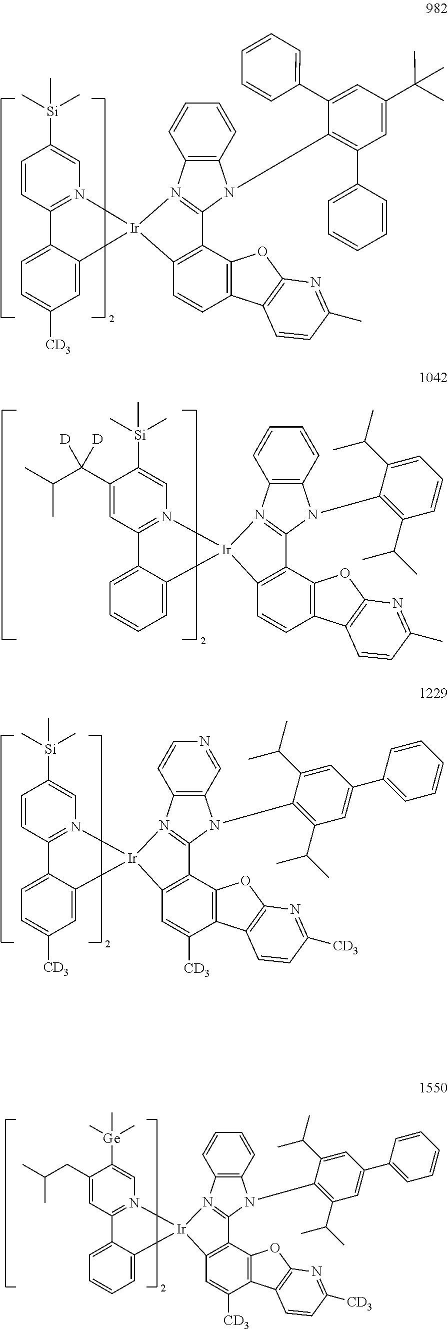

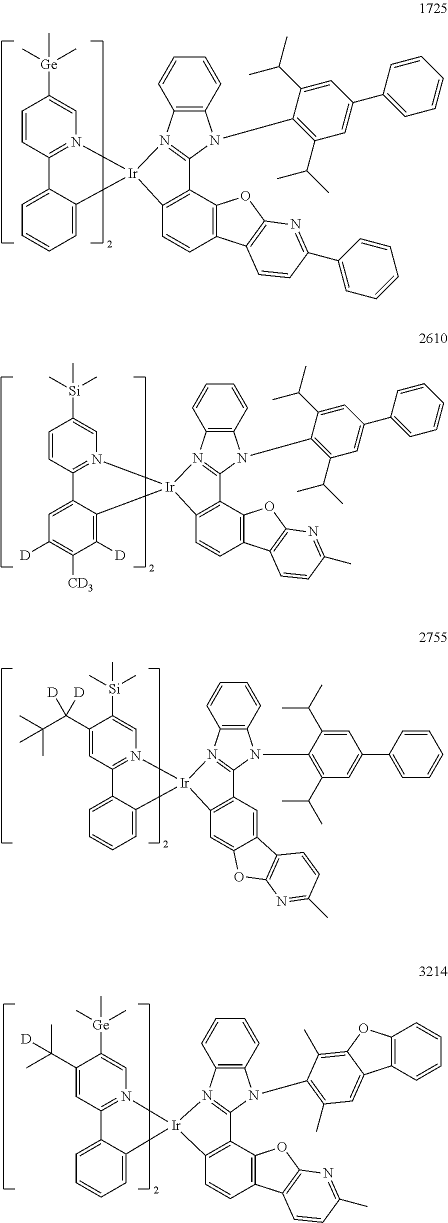

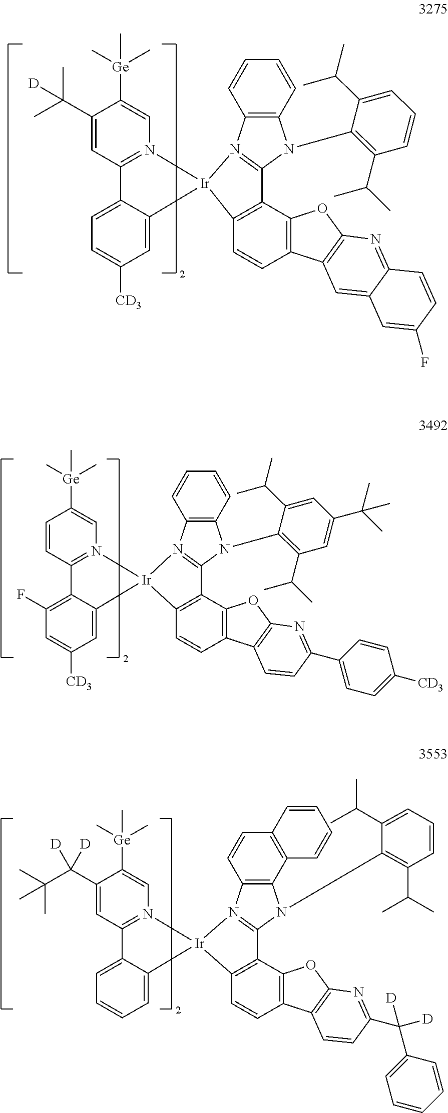

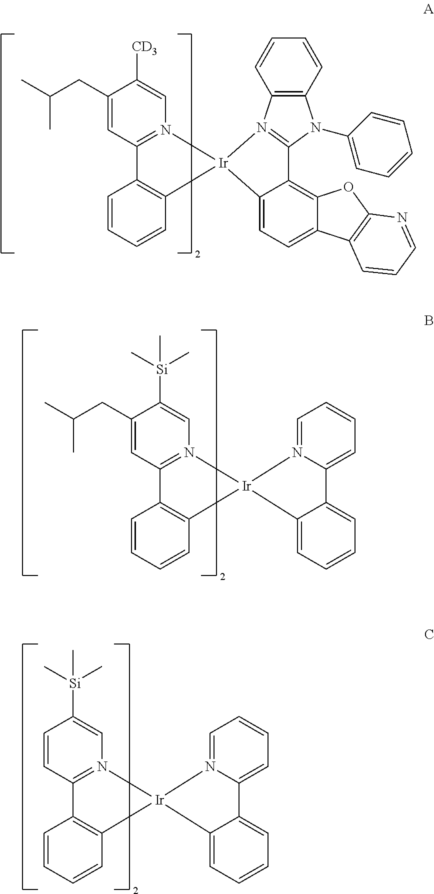

From Table 2, it was confirmed that the organic light-emitting devices of Example 1 to 15 may have improved external quantum efficiency, improved roll-off ratio, and improved lifespan characteristics compared to the organic light-emitting devices of Comparative Examples A to C.

The organometallic compound has excellent electrical characteristics, and thus an electronic device including the organometallic compound, for example, an organic light-emitting device, may have improved external quantum efficiency and improved lifespan characteristics.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims.

What is claimed is:

1. An organometallic compound represented by Formula 1:
M(L₁)ₙ₁(L₂)ₙ₂ Formula 1
wherein, in Formula 1,
M is a transition metal,
L₁ is a ligand represented by Formula 2,
L₂ is a ligand represented by Formula 3,
n1 and n2 are each independently 1 or 2, when n1 is 2, two L₁ groups are identical to or different from each other, and when n2 is 2, two L₂ groups are identical to or different from each other. 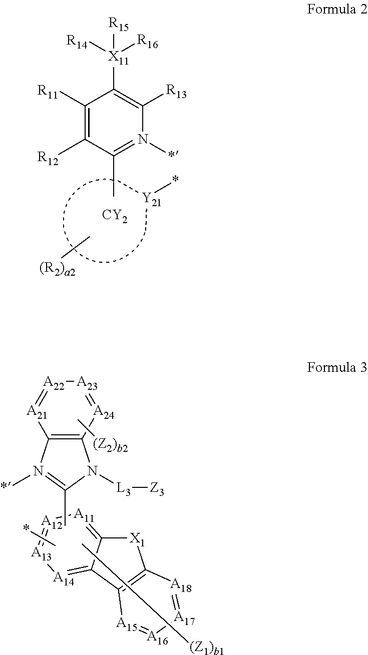
wherein, in Formulae 2 and 3,
Y₂₁ is C or N,
ring CY₂ is a C₅-C₃₀ carbocyclic group or C₁-C₃₀ heterocyclic group,
X₁₁ is Si or Ge,
X₁ is O, S, Se, N(Z₁₉), or Si(Z₁₉)(Z₂₀),
A₁₁ to A₁₄ are each independently C or N, wherein one of A₁₁ to A₁₄ is C bonded to a group represented by 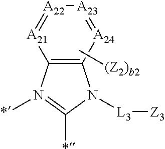
in Formula 3, and one of remaining A₁₁ to A₁₄ is C bonded to M in Formula 1,
A₁₅ to A₁₈ are each independently C or N,
A₂₁ to A₂₄ are each independently C,
at least one of A₁₁ to A₁₈ is N,
L₃ is a single bond, a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
R₂, R₁₁ to R₁₆, Z₁ to Z₃, Z₁₉, and Z₂₀ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
a2 is an integer from 0 to 20, and when a2 is 2 or more, two or more R₂ groups are identical to or different from each other,
b1 is an integer from 0 to 5, and when b1 is 2 or more, two or more Z₁ groups are identical to or different from each other,
b2 is an integer from 0 to 4, and when b2 is 2 or more, two or more Z₂ groups are identical to or different from each other,
R₁₁ and R₁₂ are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
two or more of a plurality of R₂ groups are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
two or more of a plurality of Z₁ groups are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
two or more of a plurality of Z₂ groups are optionally linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
provided that, when two or more of a plurality of Z₁ groups are linked to each other to form a C₅-C₃₀ carbocyclic group that is unsubstituted or substituted with at least one R₁₀ₐ, or a C₁-C₃₀ heterocyclic group that is unsubstituted or substituted with at least one R₁₀ₐ, then L₃ is a C₅-C₃₀ carbocyclic group that is unsubstituted or substituted with at least one R₁₀ₐ, or a C₁-C₃₀ heterocyclic group that is unsubstituted or substituted with at least one R₁₀ₐ,
R₁₀ₐ is deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted C₂-C₆₀ alkylheteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉), and
* and *′ each indicate a binding site to M in Formula 1,
wherein a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₇-C₆₀ arylalkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted C₂-C₆₀ alkylheteroaryl group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, carboxylic acid group or a salt thereof, sulfonic acid group or a salt thereof, phosphoric acid group or a salt thereof, a C₁-C₆₀ alkyl group, a C₂-C₆₀ alkenyl group, a C₂-C₆₀ alkynyl group, C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, carboxylic acid group or a salt thereof, sulfonic acid group or a salt thereof, phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a C₂-C₆₀ alkylheteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or a combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, carboxylic acid group or a salt thereof, sulfonic acid group or a salt thereof, phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or a combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
a combination thereof;
wherein Q₁ to Q₉, Q₁₁ to Q₁₉, Q₂₁ to Q₂₉, and Q₃₁ to Q₃₉ are each independently: hydrogen; deuterium; —F; —Cl; —Br; —I; a hydroxyl group; a cyano group; a nitro group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, —F, a C₁-C₆₀ alkyl group, a C₆-C₆₀ aryl group, or a combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, —F, a C₁-C₆₀ alkyl group, a C₆-C₆₀ aryl group, or a combination thereof; a C₆-C₆₀ aryloxy group; a C₆-C₆₀ arylthio group; a C₇-C₆₀ arylalkyl group; a C₁-C₆₀ heteroaryl group; a C₁-C₆₀ heteroaryloxy group; a C₁-C₆₀ heteroarylthio group; a C₂-C₆₀ heteroarylalkyl group; a C₂-C₆₀ alkylheteroaryl group; a monovalent non-aromatic condensed polycyclic group; or a monovalent non-aromatic condensed heteropolycyclic group.

2. The organometallic compound of claim 1, wherein
the ring CY₂ is a benzene group, a naphthalene group, an anthracene group, a phenanthrene group, a 1,2,3,4-tetrahydronaphthalene group, a carbazole group, a fluorene group, a dibenzosilole group, a dibenzothiophene group, or a dibenzofuran group.

3. The organometallic compound of claim 1, wherein
L₃ in Formula 3 is:
a single bond; or
a benzene group, a naphthalene group, a dibenzofuran group, or a dibenzothiophene group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof.

4. The organometallic compound of claim 1, wherein
R₂, R₁₁ to R₁₃, Z₁ to Z₃, Z₁₉ and Z₂₀ in Formulae 2 and 3 are each independently:
hydrogen, deuterium, —F, or a cyano group; or
a C₁-C₂₀ alkyl group, a C₃-C₁₀ cycloalkyl group, a phenyl group, a naphthyl group, a pyridinyl group, a furanyl group, a thiophenyl group, a benzofuranyl group, a benzothiophenyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, —Si(Q₃₃)(Q₃₄)(Q₃₅), —Ge(Q₃₃)(Q₃₄)(Q₃₅), or a combination thereof; and
R₁₄ to R₁₆ in Formula 2 are each independently a C₁-C₂₀ alkyl group, a C₃-C₁₀ cycloalkyl group, a phenyl group, a naphthyl group, a pyridinyl group, a furanyl group, a thiophenyl group, a benzofuranyl group, a benzothiophenyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a phenyl group, a deuterated phenyl group, a fluorinated phenyl group, a (C₁-C₂₀ alkyl)phenyl group, a naphthyl group, a pyridinyl group, a furanyl group, a thiophenyl group, a benzofuranyl group, a benzothiophenyl group, a dibenzofuranyl group, a dibenzothiophenyl group, or a combination thereof.

5. The organometallic compound of claim 1, wherein
R₁₁ is not hydrogen.

6. The organometallic compound of claim 1, wherein satisfying at least one of Condition A and Condition B:
Condition A
L₃ is a C₅-C₃₀ carbocyclic group unsubstituted or substituted with at least one R₁₀ₐ, or a C₁-C₃₀ heterocyclic group unsubstituted or substituted with at least one R₁₀ₐ,
Condition B
Z₃ is a substituted or unsubstituted C₆-C₆₀ aryl group, a substituted or unsubstituted C₁-C₆₀ heteroaryl group, a substituted or unsubstituted monovalent non-aromatic condensed polycyclic group, or a substituted or unsubstituted monovalent non-aromatic condensed heteropolycyclic group.

7. The organometallic compound of claim 1, wherein
Z₁ is not hydrogen, and b1 is an integer from 1 to 5.

8. The organometallic compound of claim 1, wherein
b1 is an integer from 1 to 5,
at least one of Z₁ is a substituted C₁-C₆₀ alkyl group, and
a substituent of the substituted C₁-C₆₀ alkyl group comprises a C₆-C₆₀ aryl group, a C₁-C₆₀ heteroaryl group, a monovalent non-aromatic condensed polycyclic group, or a monovalent non-aromatic condensed heteropolycyclic group, each unsubstituted or substituted with deuterium, —F, —CD₃, —CD₂H, —CDH₂, —CF₃, —CF₂H, —CFH₂, a cyano group, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, or a combination thereof.

9. The organometallic compound of claim 1, wherein
the group represented by: 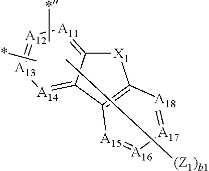
in Formula 3 is a group represented by one of Formulae CY3-1 to CY3-6: 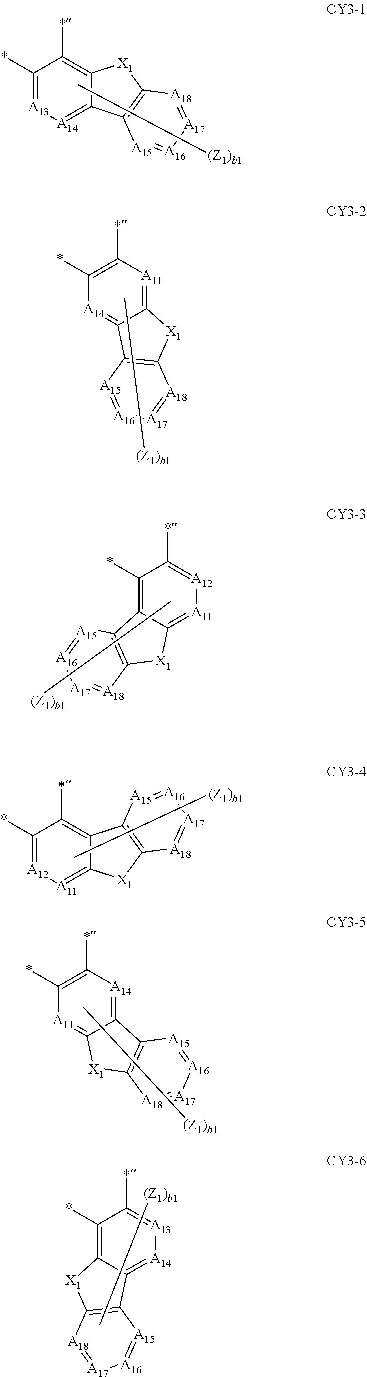
wherein, in Formulae CY3-1 to CY3-6,
X₁, Z₁ and b1 are the same as defined in claim 1,
A₁₁ to A₁₈ are each independently C or N, wherein at least one of A₁₃ to A₁₈ in Formulae CY3-1 and CY3-6 is N, at least one of A₁₁, A₁₄, A₁₅, A₁₆, A₁₇ and A₁₈ in Formulae CY3-2 and CY3-5 is N, and at least one of A₁₁, A₁₂, A₁₅, A₁₆, A₁₇ and A₁₈ in Formulae CY3-3 and CY3-4 is N,
* indicates a binding site to M in Formula 1, and
*″ indicates a binding site to a neighboring atom in Formula 3.

10. The organometallic compound of claim 1, wherein
L₃ is a single bond, a C₅-C₃₀ carbocyclic group that is unsubstituted or substituted with at least one R₁₀ₐ, or a C₁-C₃₀ heterocyclic group that is unsubstituted or substituted with at least one R₁₀ₐ, and
a group represented by: 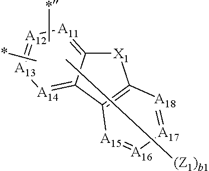
in Formula 3 is a group represented by one of Formulae CY3-1-1 to CY3-1-6, CY3-2-1 to CY3-2-6, CY3-3-1 to CY3-3-6, CY3-4-1 to CY3-4-6, CY3-5-1 to CY3-5-6, and CY3-6-1 to CY3-6-6: 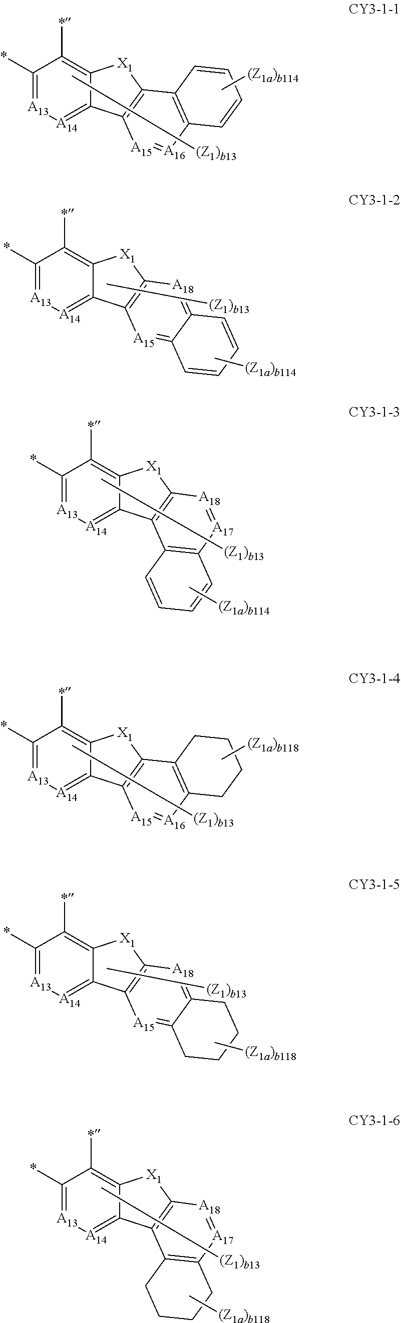 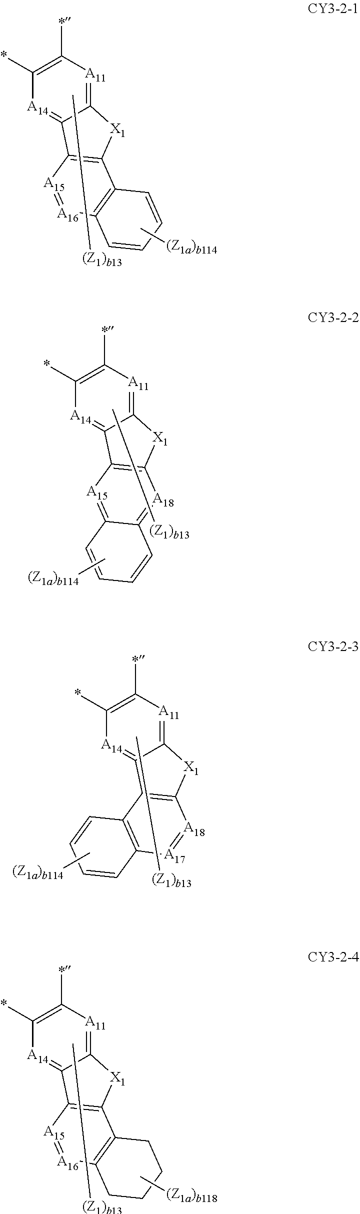 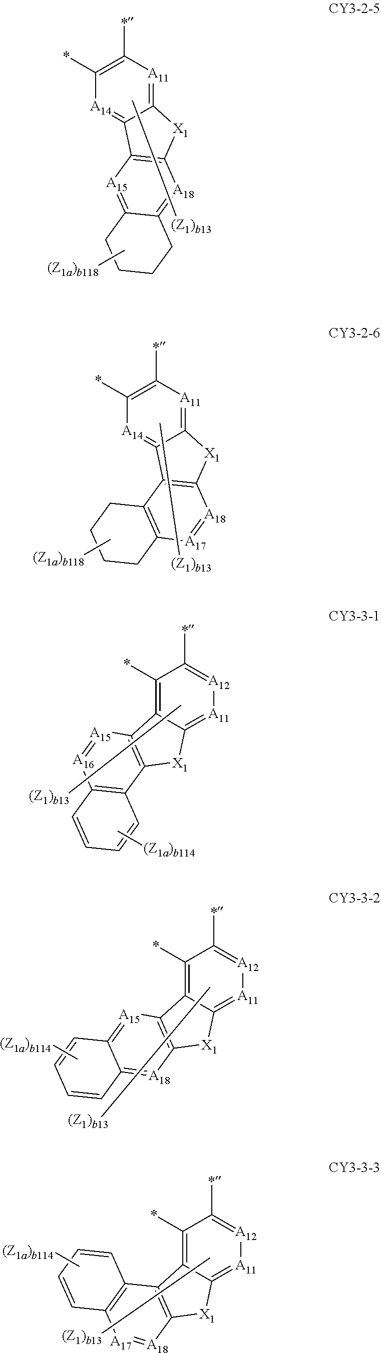 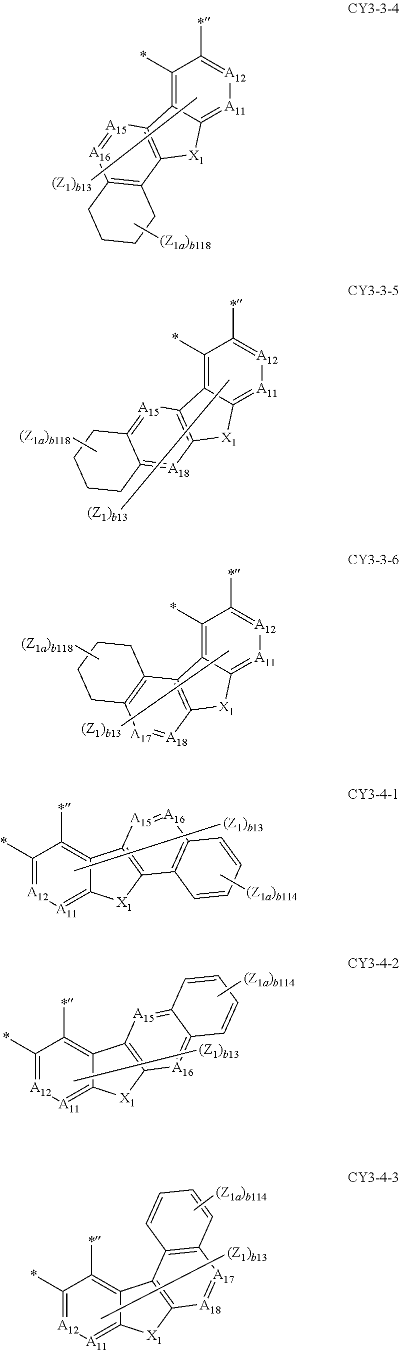 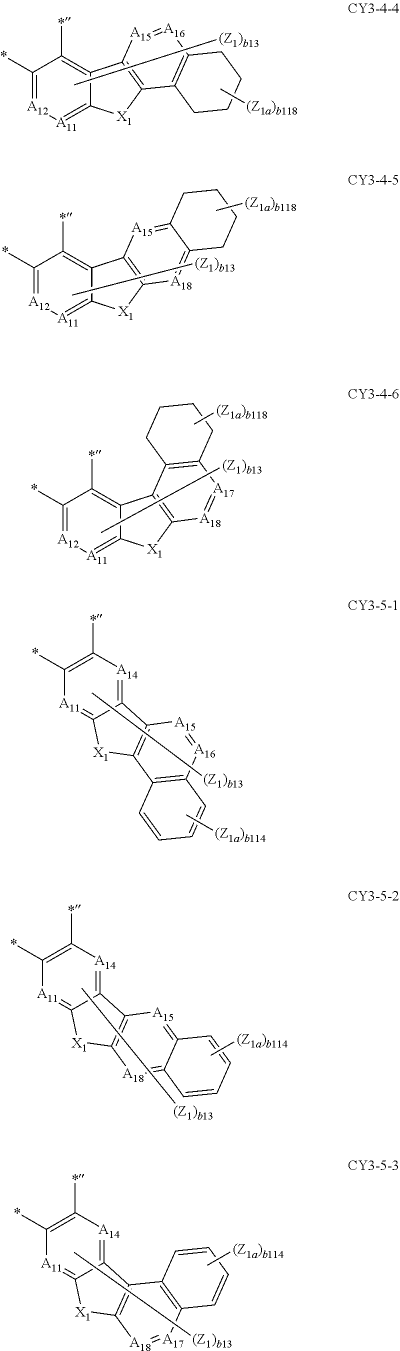 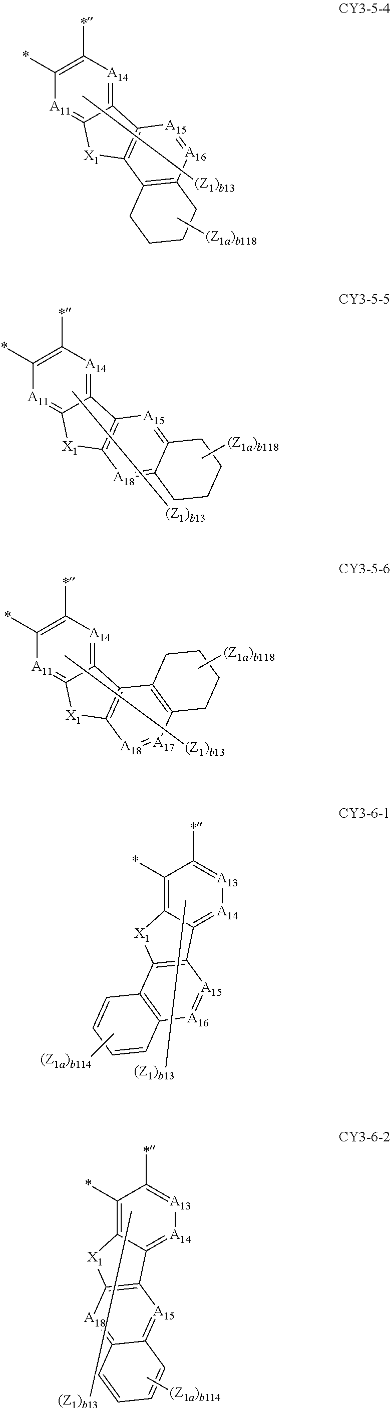 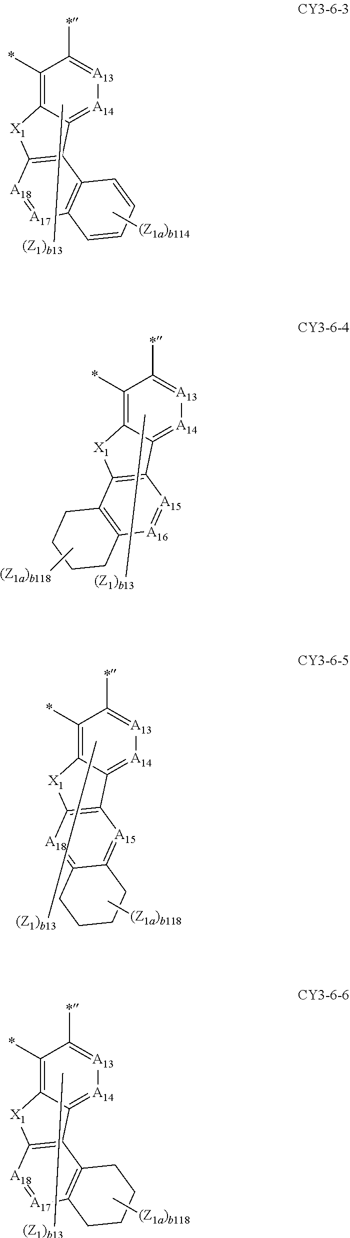
wherein, in Formulae CY3-1-1 to CY3-1-6, CY3-2-1 to CY3-2-6, CY3-3-1 to CY3-3-6, CY3-4-1 to CY3-4-6, CY3-5-1 to CY3-5-6, and CY3-6-1 to CY3-6-6,
X₁ and Z₁ are the same as defined in claim 1,
Z₁ₐ is the same as defined in claim 1 in connection with R₁ₐ,
A₁₁ to A₁₈ are each independently C or N, wherein a) at least one of A₁₃, A₁₄, A₁₅, and A₁₆ in Formulae CY3-1-1, CY3-1-4, CY3-6-1, and CY3-6-4 is N, b) at least one of A₁₃, A₁₄, A₁₅, and A₁₈ in Formulae CY3-1-2, CY3-1-5, CY3-6-2, and CY3-6-5 is N, c) at least one of A₁₃, A₁₄, A₁₇, and A₁₈ in Formulae CY3-1-3, CY3-1-6, CY3-6-3, and CY3-6-6 is N, d) at least one of A₁₁, A₁₄, A₁₅, and A₁₆ in Formulae CY3-2-1, CY3-2-4, CY3-5-1, and CY3-5-4 is N, e) at least one of A₁₁, A₁₄, A₁₅, and A₁₈ in Formulae CY3-2-2, CY3-2-5, CY3-5-2, and CY3-5-5 is N, f) at least one of A₁₁, A₁₄, A₁₇, and A₁₈ in Formulae CY3-2-3, CY3-2-6, CY3-5-3, and CY3-5-6 is N, g) at least one of A₁₁, A₁₂, A₁₅, and A₁₆ in Formulae CY3-3-1, CY3-3-4, CY3-4-1, and CY3-4-4 is N, h) at least one of A₁₁, A₁₂, A₁₅, and A₁₈ in Formulae CY3-3-2, CY3-3-5, CY3-4-2, and CY3-4-5 is N, i) at least one of A₁₁, A₁₂, A₁₇, and A₁₈ in Formulae CY3-3-3, CY3-3-6, CY3-4-3, and CY3-4-6 is N,
b13 is an integer from 0 to 3,
b114 is an integer from 0 to 4,
b118 is an integer from 0 to 8,
* indicates a binding site to M in Formula 1, and
*″ indicates a binding site to a neighboring atom in Formula 3.

11. The organometallic compound of claim 1, wherein
a group represented by: 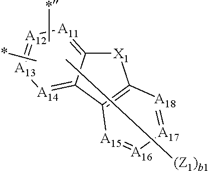
in Formula 3 is a group represented by one of Formulae NCY3(1) to NCY3(84): 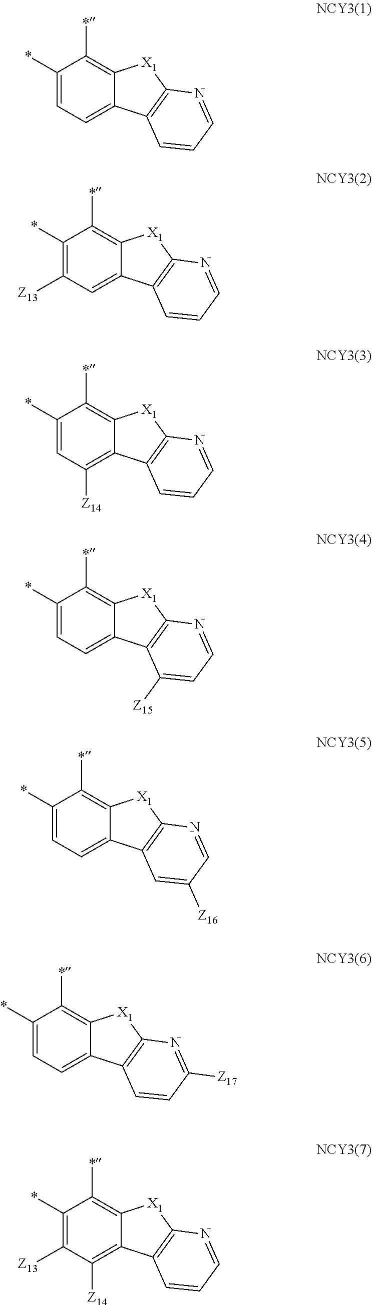 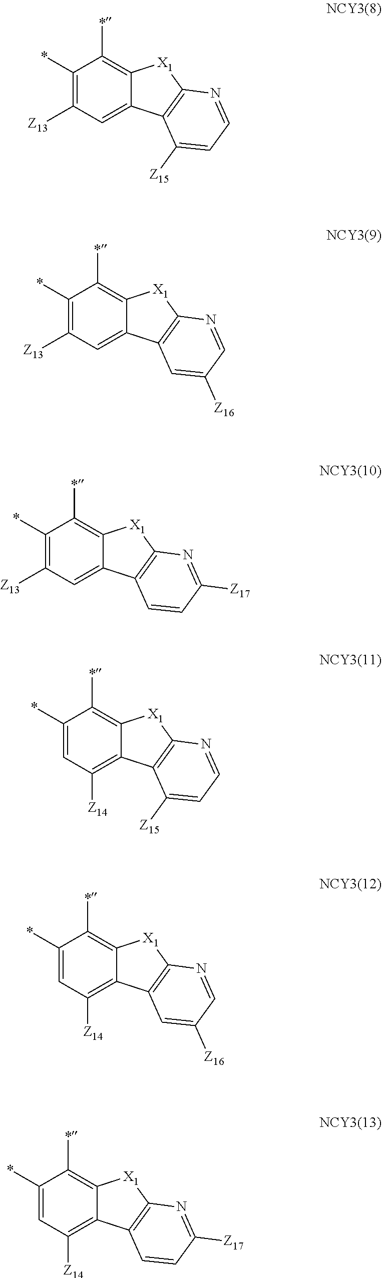 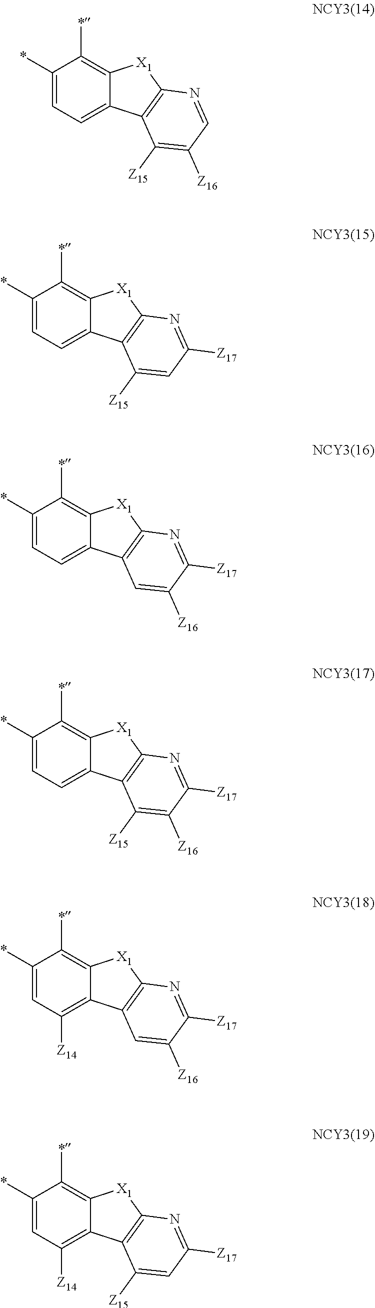 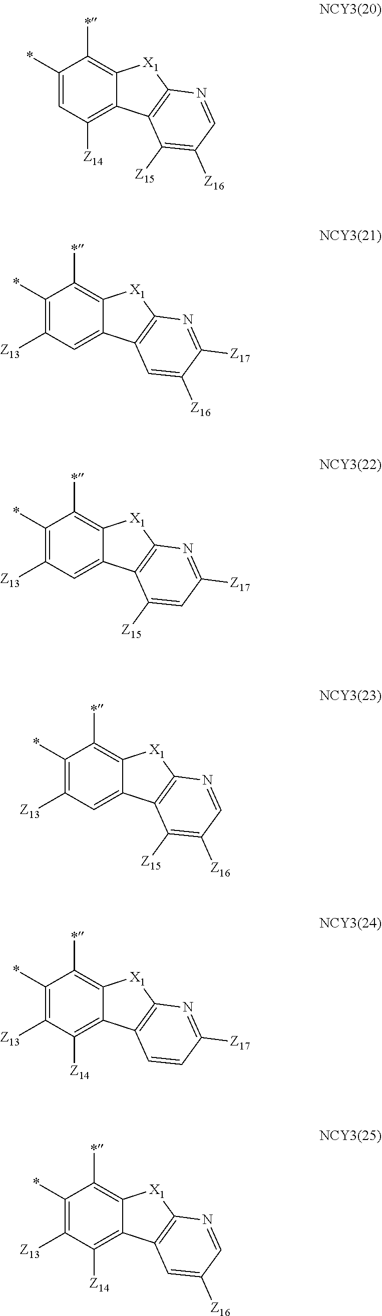 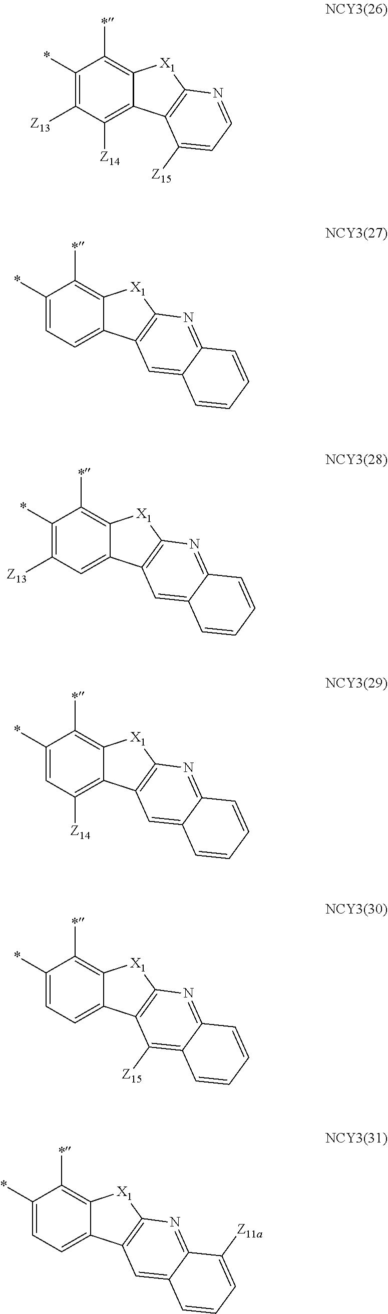 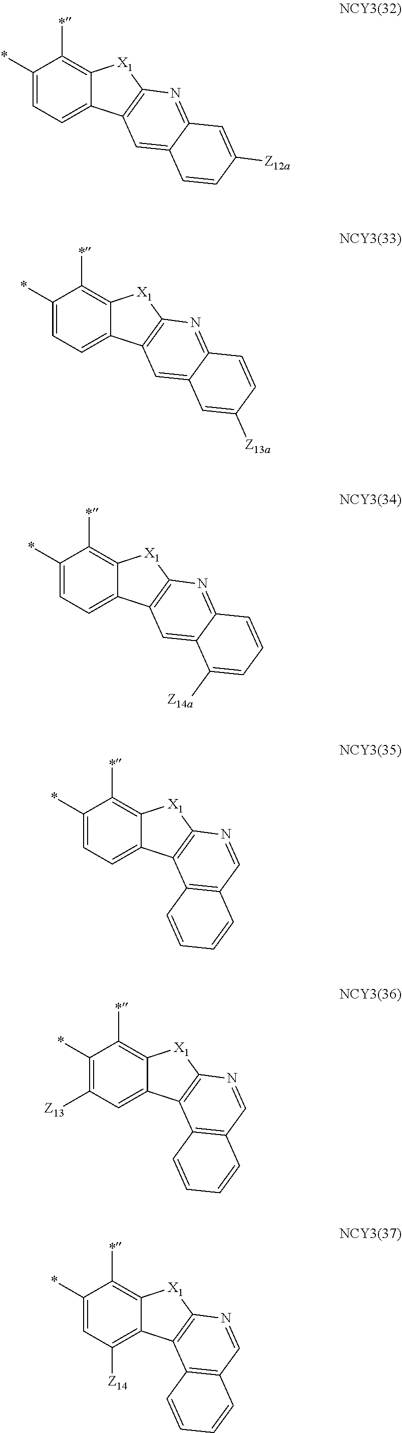 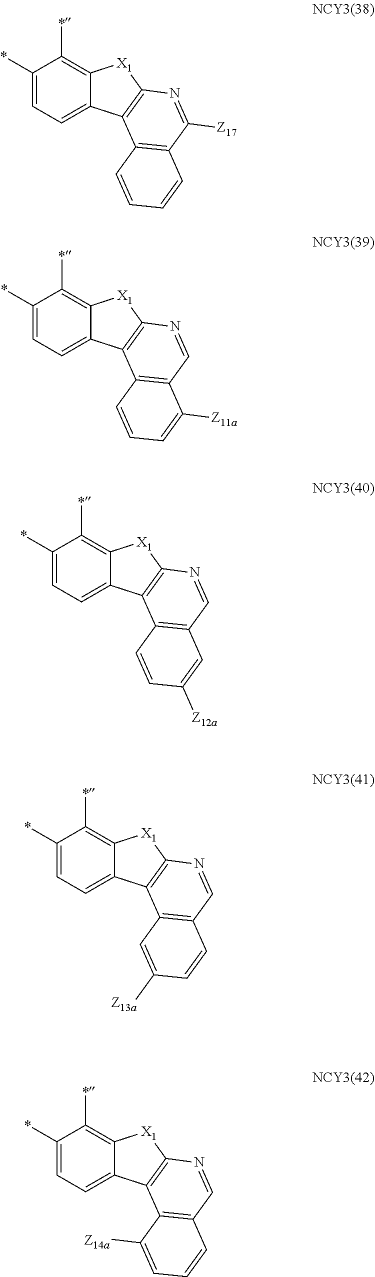 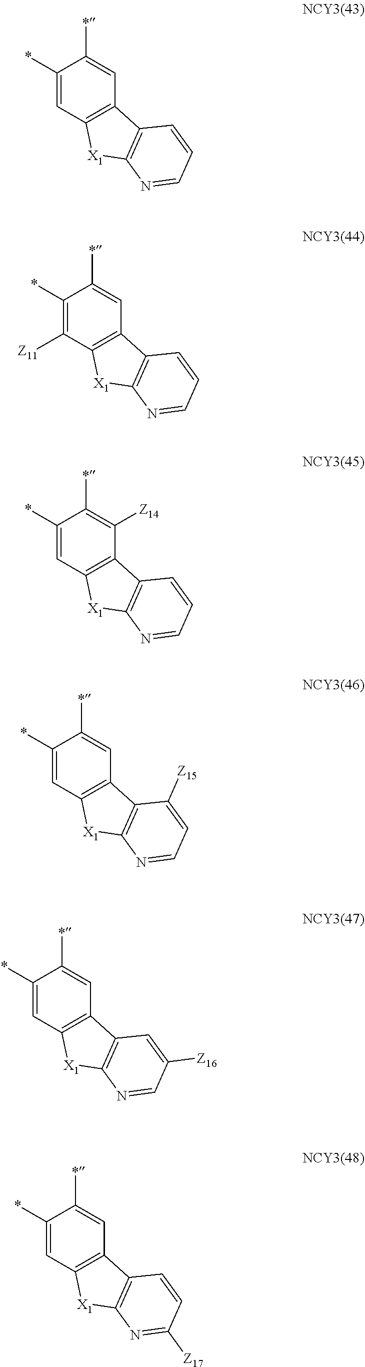 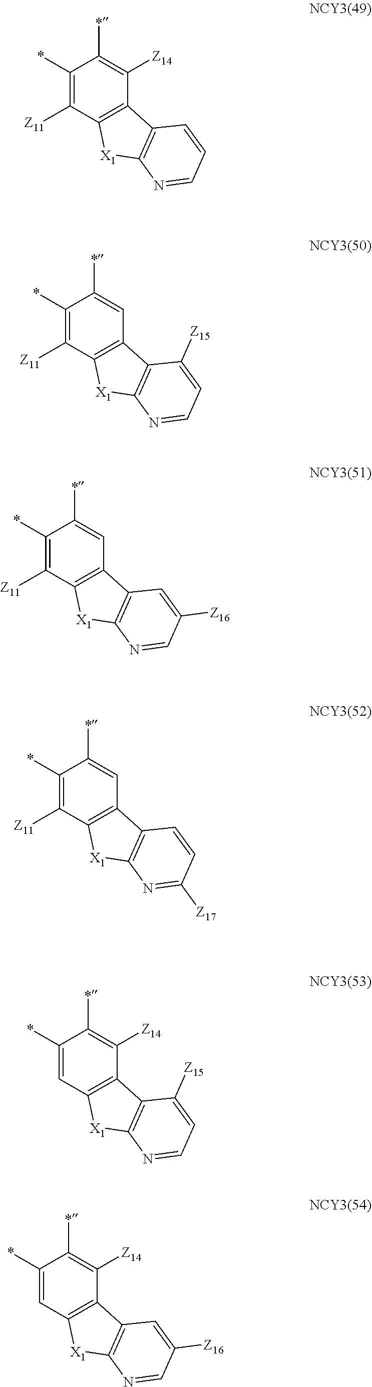 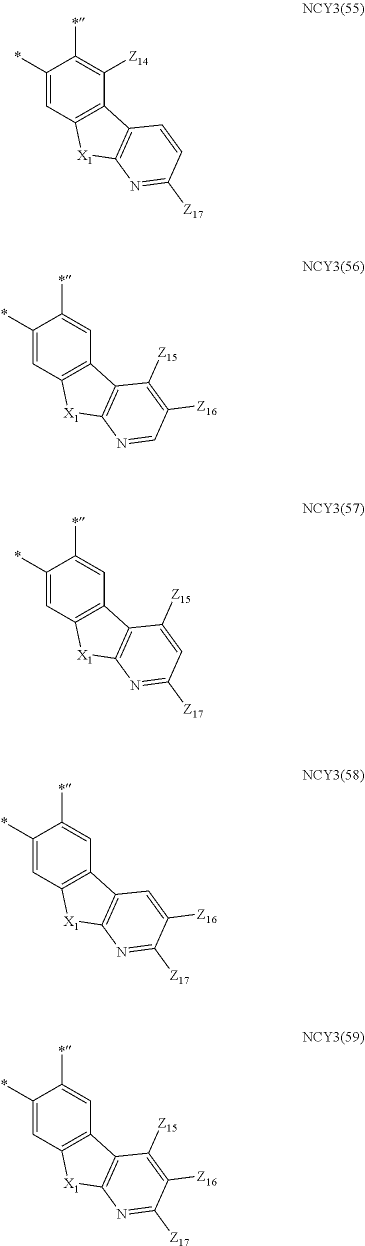 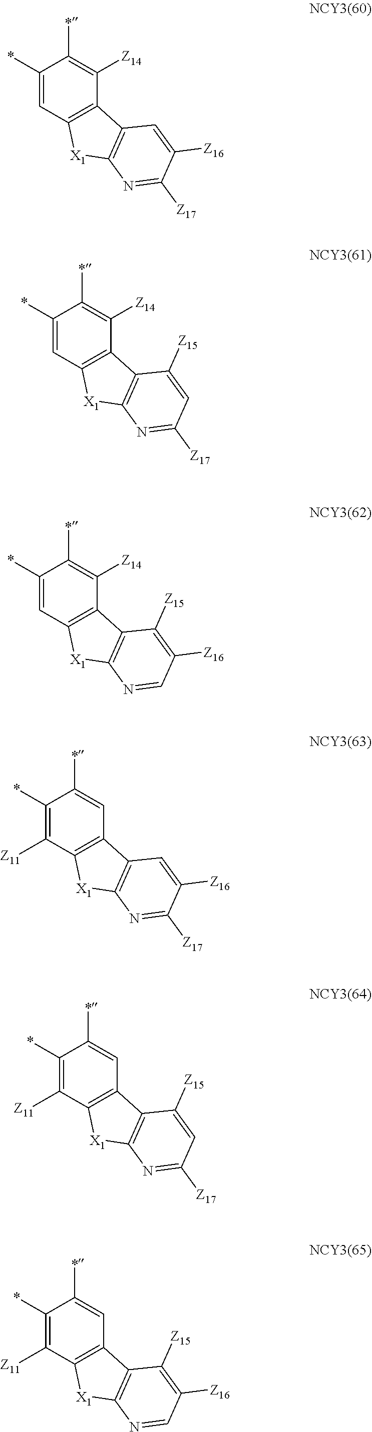 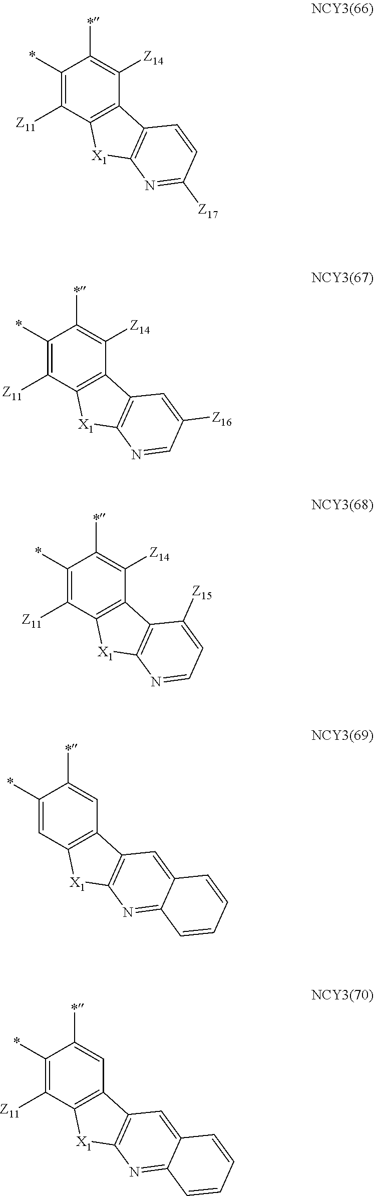 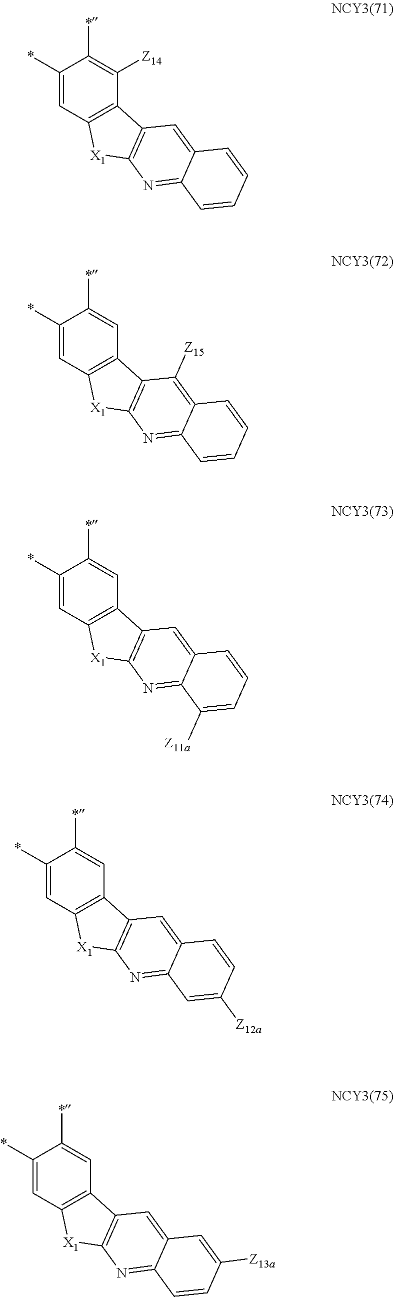 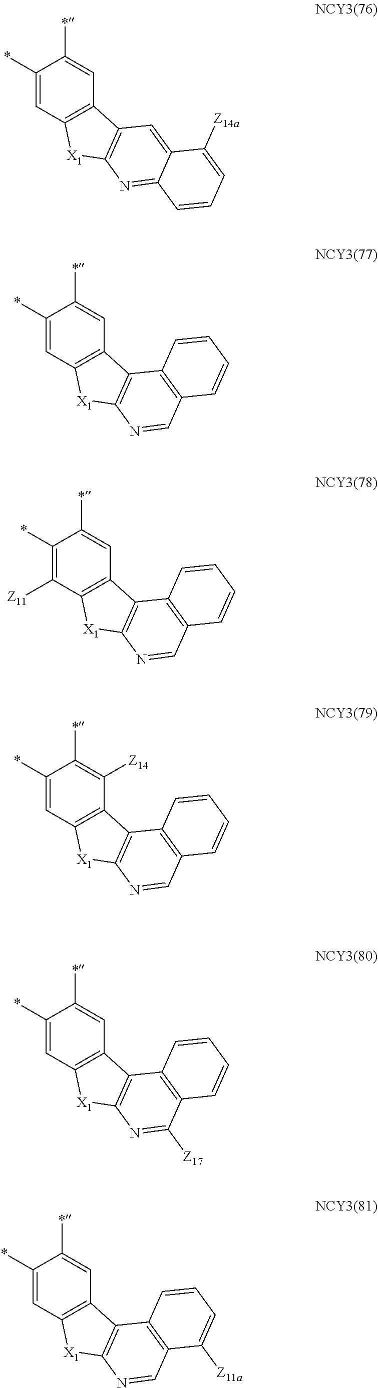 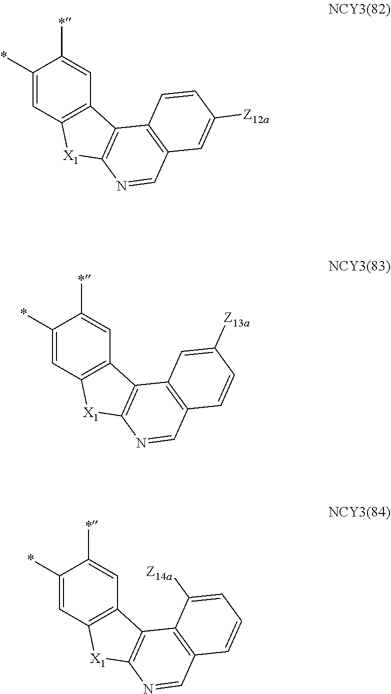
wherein, in Formulae NCY3(1) to NCY3(84),
X₁ is the same as defined in claim 1,
Z₁₁ to Z₁₈ and Z₁₁a to Z₁₄a Zia are each independently the same as defined in claim 1 in connection with Z₁, and each of Z₁₁ to Z₁₈ and Z₁₁a to Z₁₄a Zia is not hydrogen,
* indicates a binding site to M in Formula 1, and
*″ indicates a binding site to a neighboring atom in Formula 3.

12. The organometallic compound of claim 1, wherein
a group represented by: 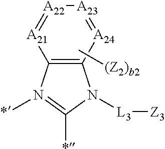
in Formula 3 is a group represented by one of Formulae CY4-1 to CY4-16: 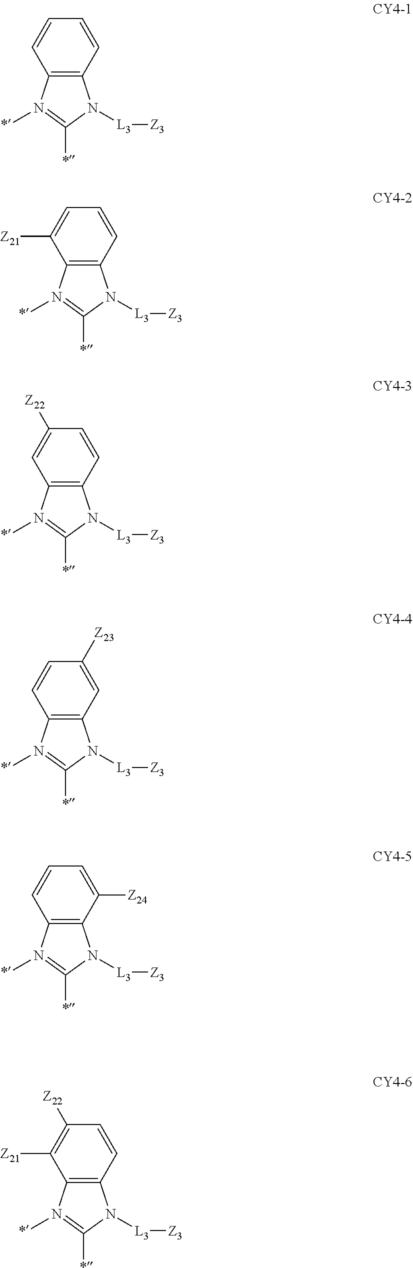 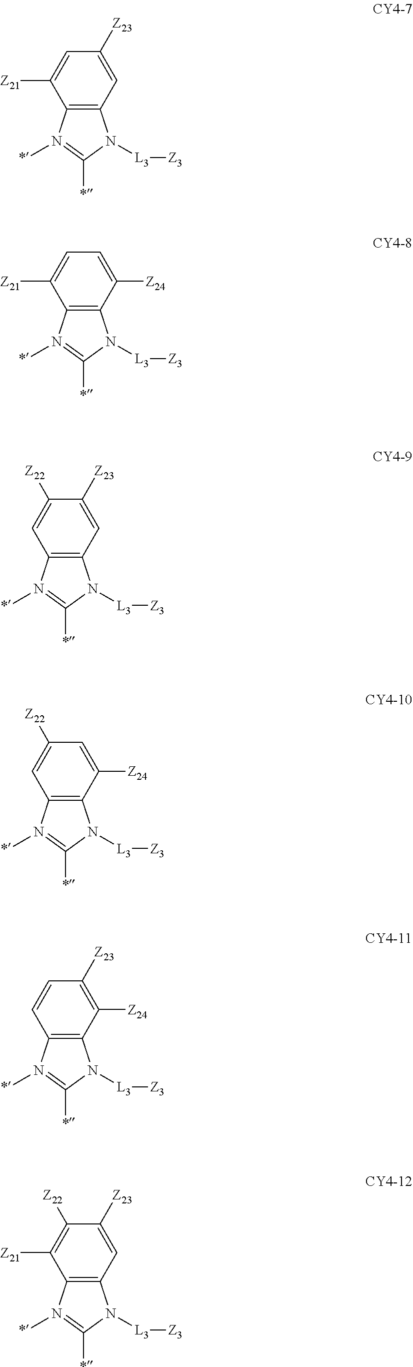 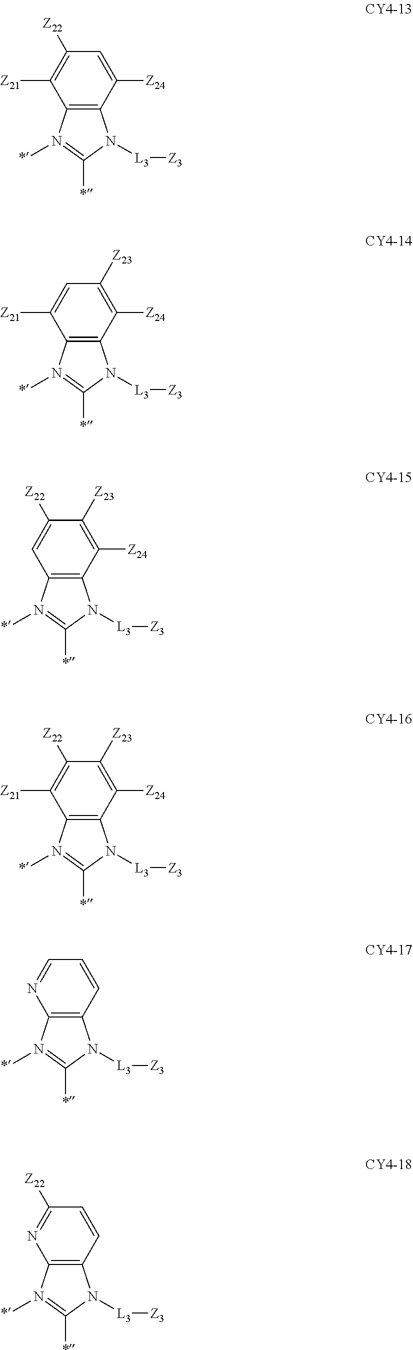 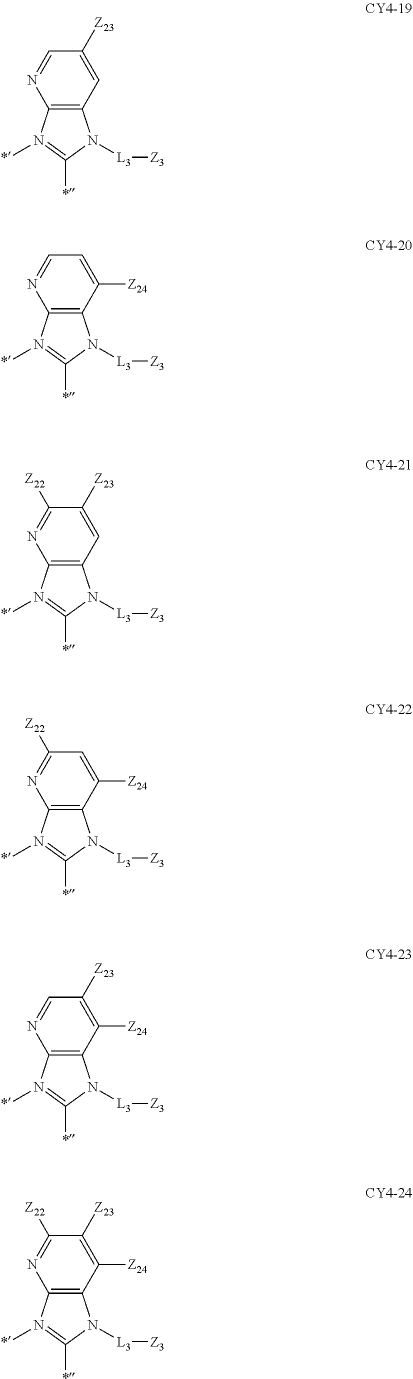 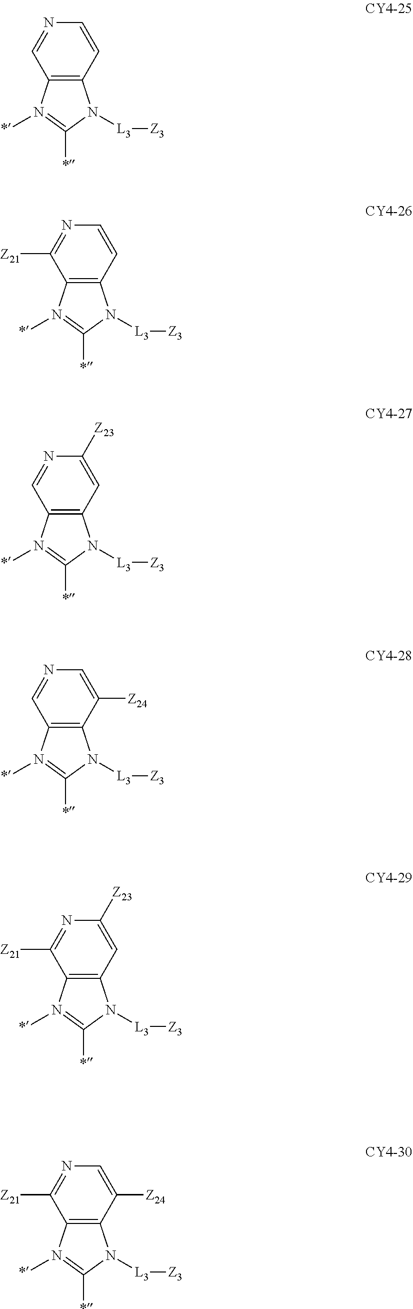 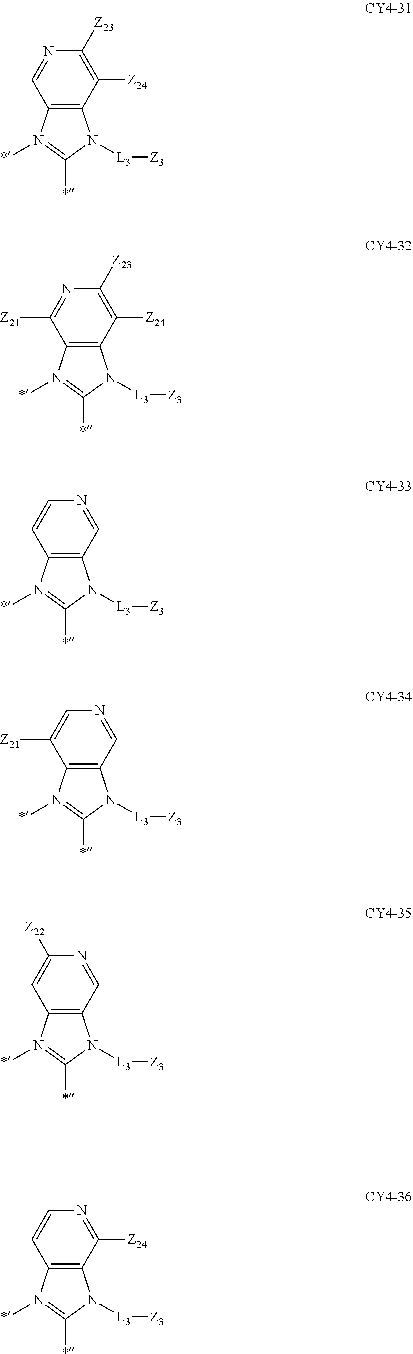 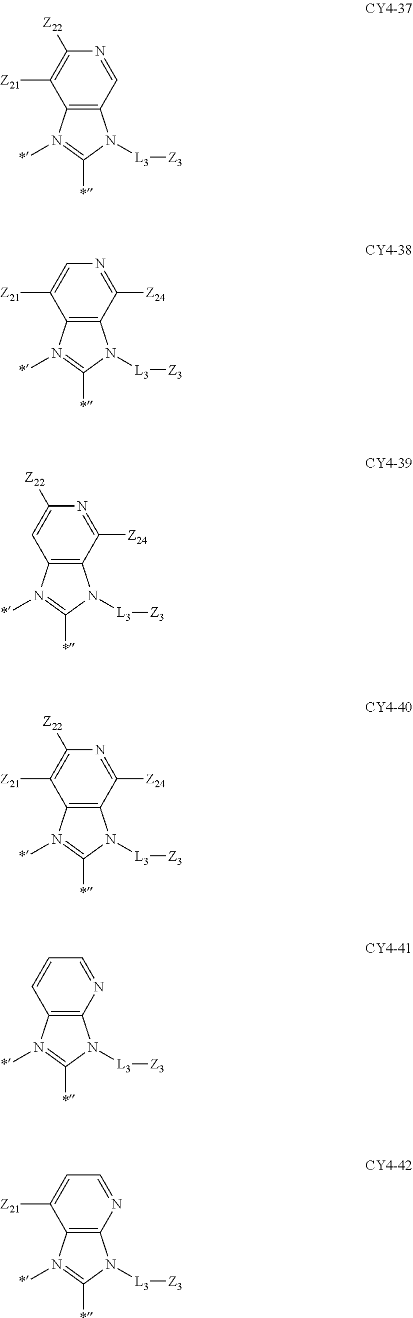 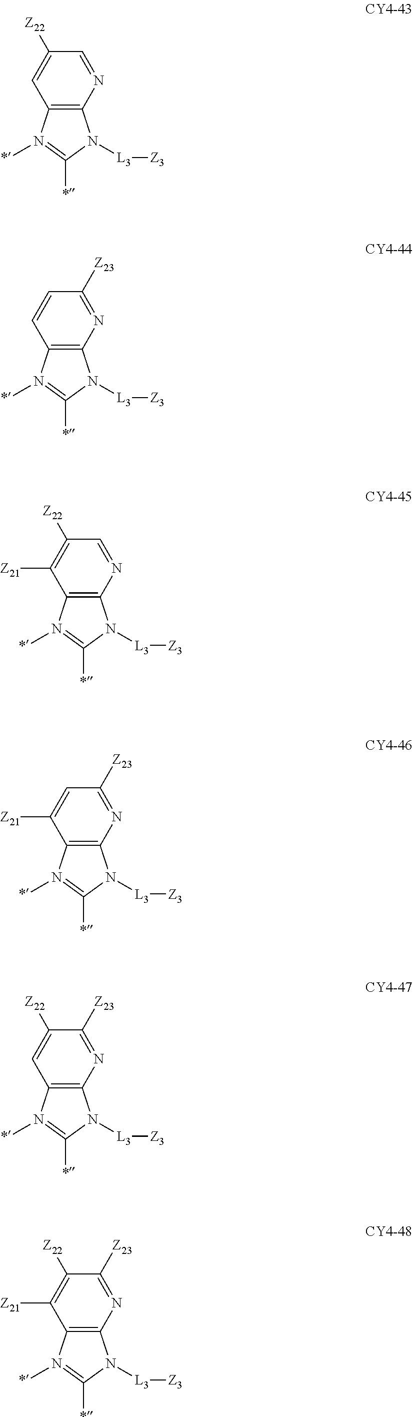 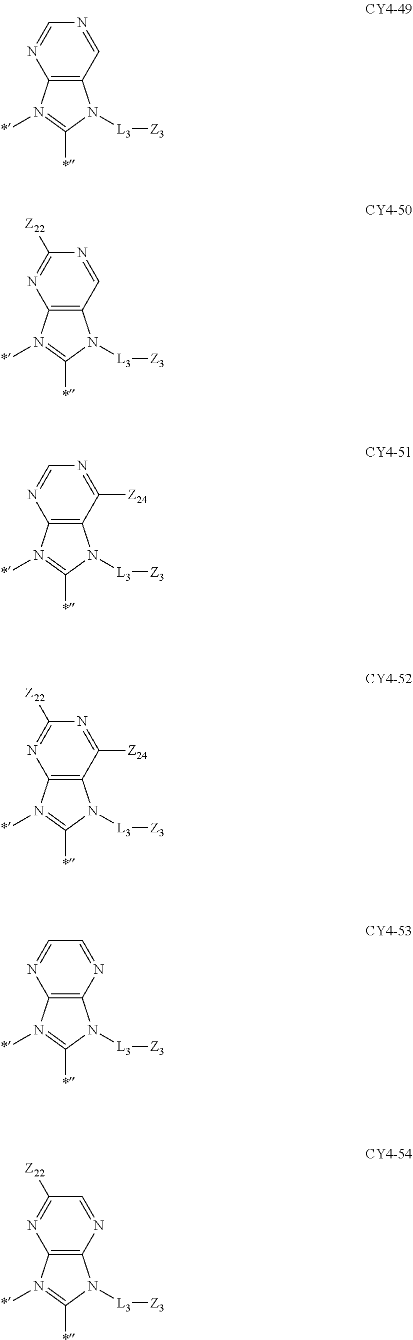 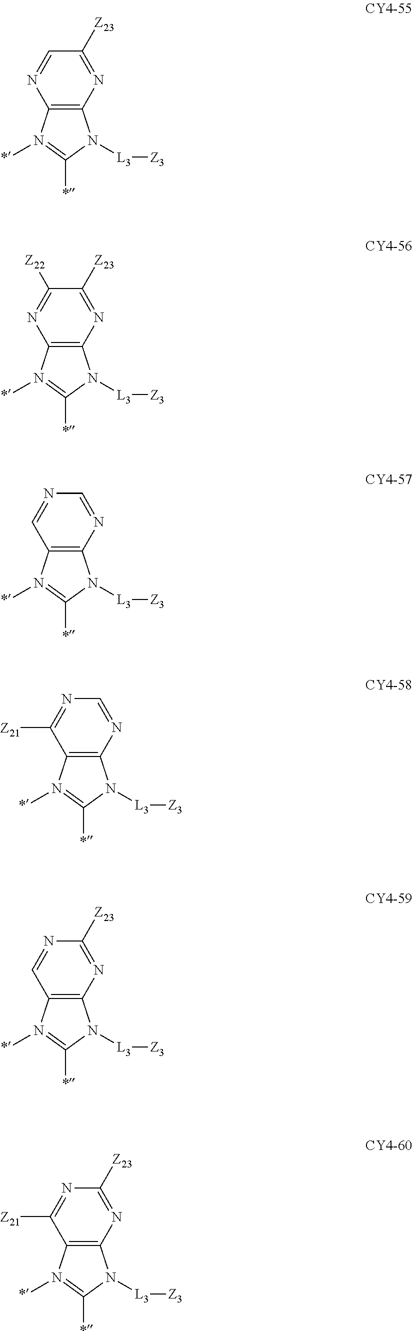
wherein, in Formulae CY4-1 to CY4-16,
L₃ and Z₃ are each independently the same as defined in claim 1,
Z₂₁ to Z₂₄ are each independently the same as defined in claim 1 in connection with Z₂, wherein Z₂₁ to Z₂₄ are not hydrogen,
*′ indicates a binding site to M in Formula 1, and
″ indicates a binding site to a neighboring atom in Formula 3.

13. The organometallic compound of claim 1, wherein
a group represented by: 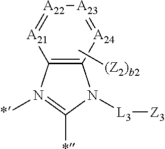
in Formula 3 is a group represented by one of Formulae CY4(1) to CY4(4): 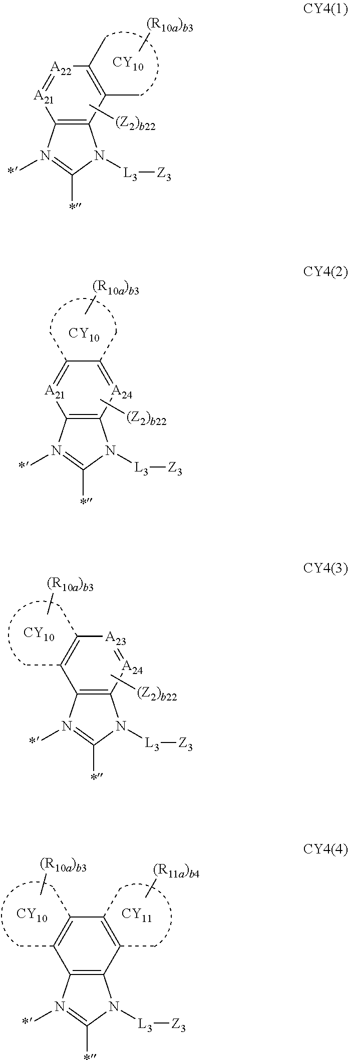
wherein, in Formulae CY4(1) to CY4(4),
A₂₁ to A₂₄, Ls, Z₂, Z₃ and R₁₀ₐ are each independently the same as defined in claim 1,
b22 is an integer from 0 to 2,
ring CY₁₀ and ring CY₁₁ are each independently a C₅-C₃₀ carbocyclic group or a C₁-C₃₀ heterocyclic group,
R₁₁ₐ is the same as defined in connection with R₁₀ₐ as defined in claim 1,
b3 and b4 are each independently an integer from 0 to 20,
when b3 is 2 or more, two or more R₁₀ₐ groups are identical to or different from each other, and
when b4 is 2 or more, two or more R₁₁ₐ groups are identical to or different from each other,
*′ indicates a binding site to M in Formula 1, and
*″ indicates a binding site to a neighboring atom in Formula 3.

14. The organometallic compound of claim 1, wherein
a group represented by: 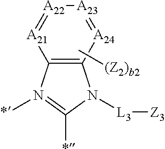
in Formula 3 is a group represented by one of Formulae CY4(1)-1 to CY4(1)-4, CY4(2)-1 to CY4(2)-4, CY4(3)-1 to CY4(3)-4 and CY4(4)-1: 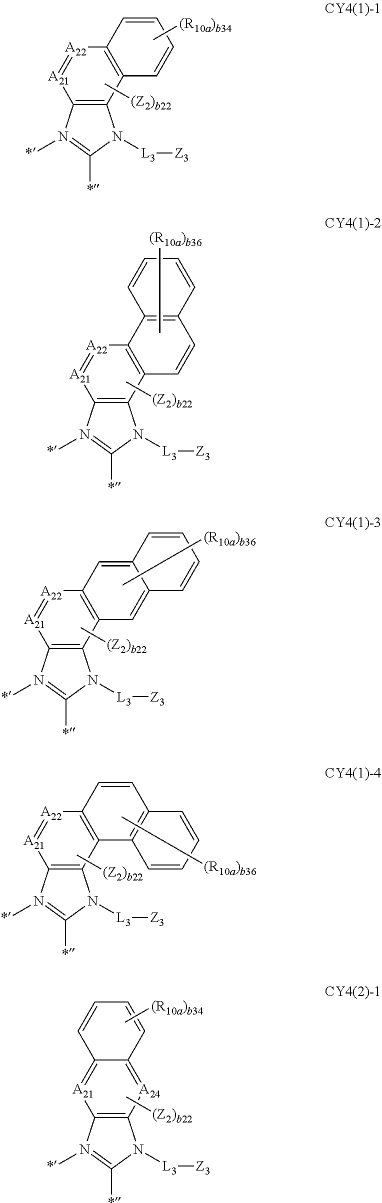 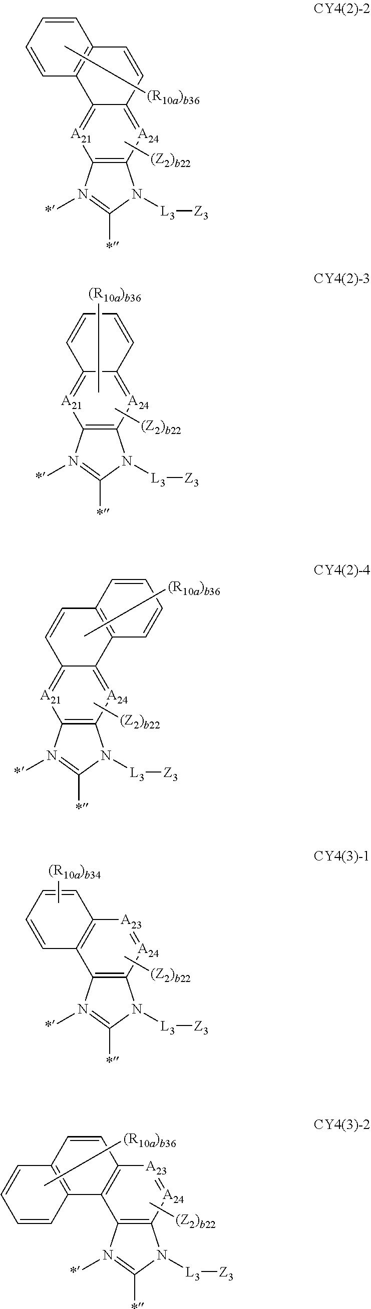 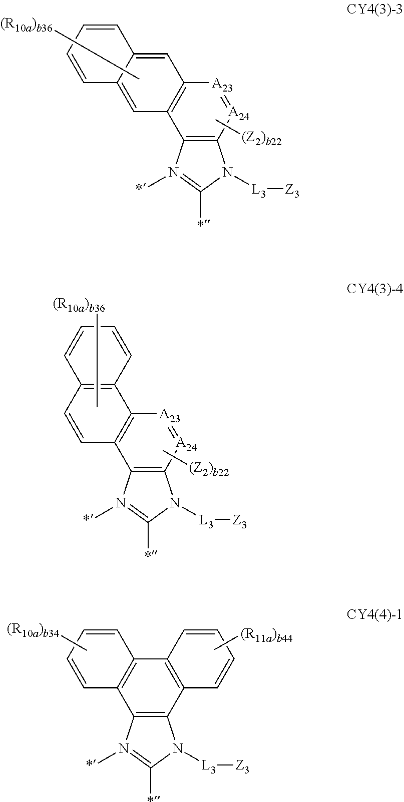
wherein, in Formulae CY4(1)-1 to CY4(1)-4, CY4(2)-1 to CY4(2)-4, CY4(3)-1 to CY4(3)-4 and CY4(4)-1,
A₂₁ to A₂₄, L₃, Z₂, Z₃ and R₁₀ₐ are each independently the same as defined in claim 1,
b22 is an integer from 0 to 2,
R₁₁ₐ is the same as defined in connection with R₁₀ₐ in claim 1,
b34 and b44 may each independently be an integer from 0 to 4, when b34 is 2 or more, two or more R₁₀ₐ(s) may be identical to or different from each other, and when b44 is 2 or more, two or more R₁₁ₐ(s) may be identical to or different from each other,
b36 may be an integer from 0 to 6, when b36 is 2 or more, two or more R₁₀ₐ (s) may be identical to or different from each other,
*′ indicates a binding site to M in Formula 1, and
*″ indicates a binding site to a neighboring atom in Formula 3.

15. An organometallic compound being one of the Compounds 1 to 4010:

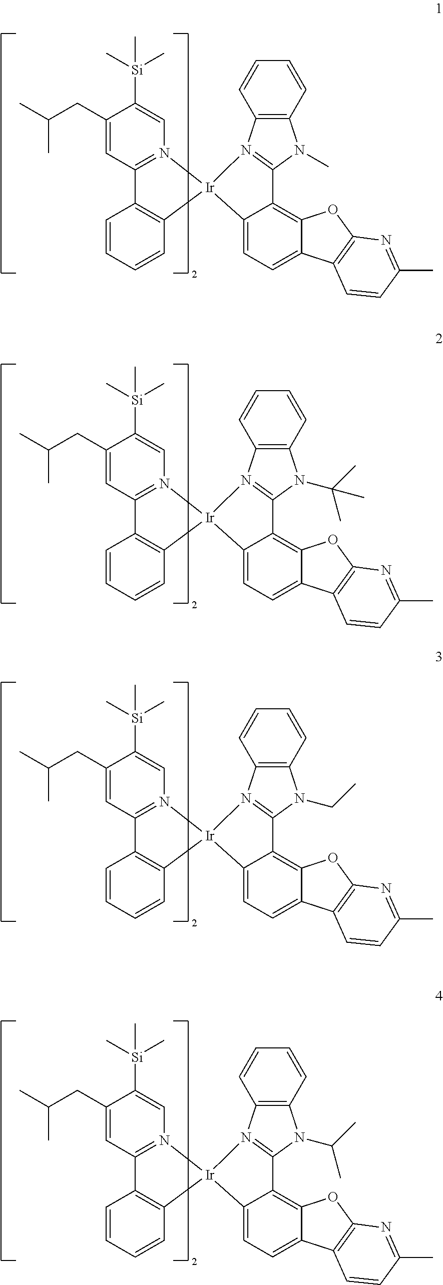

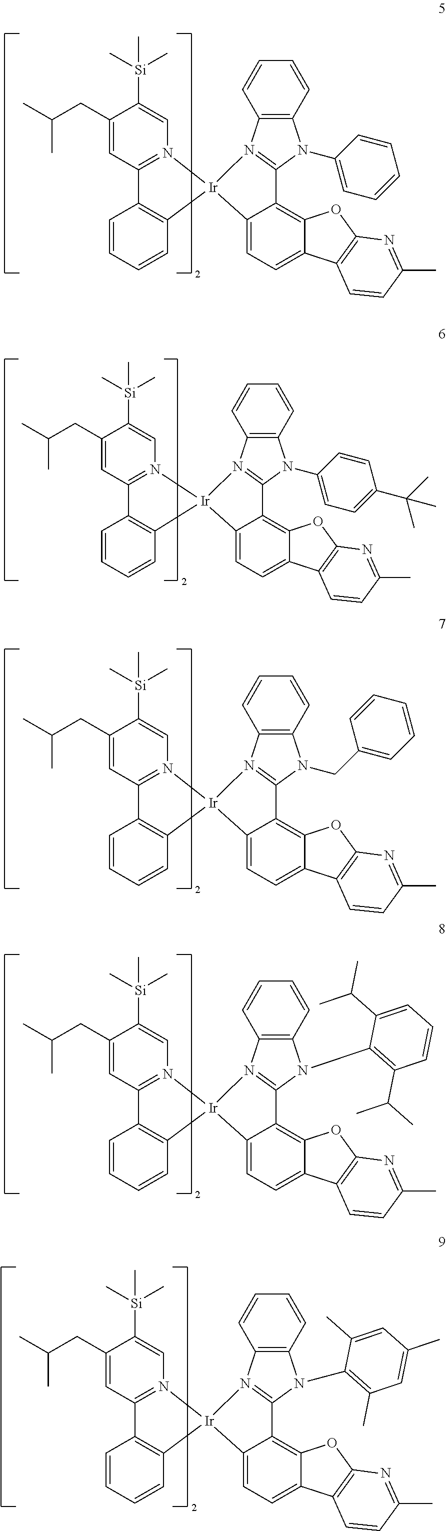

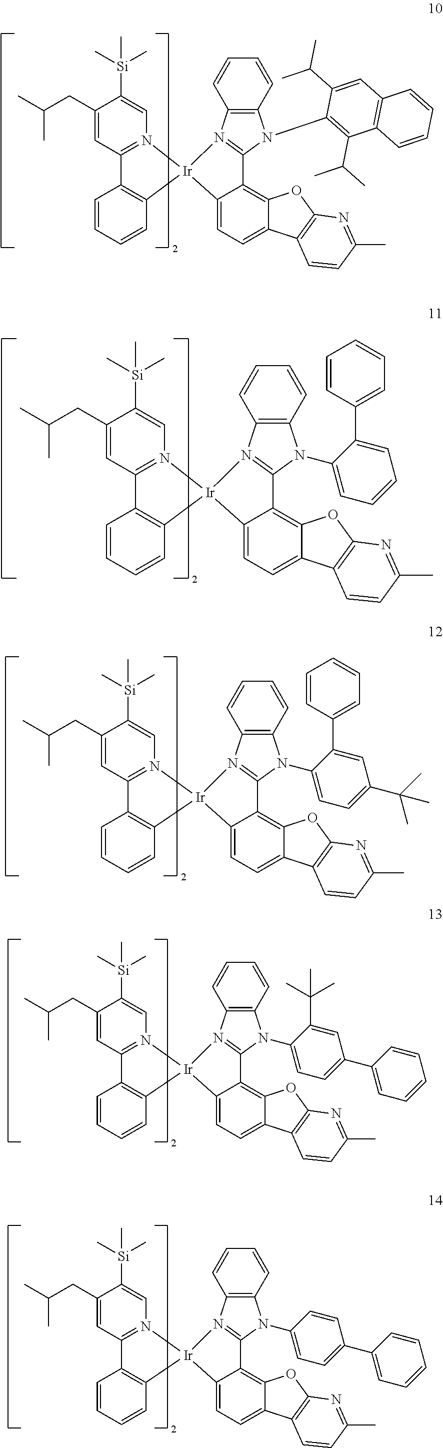

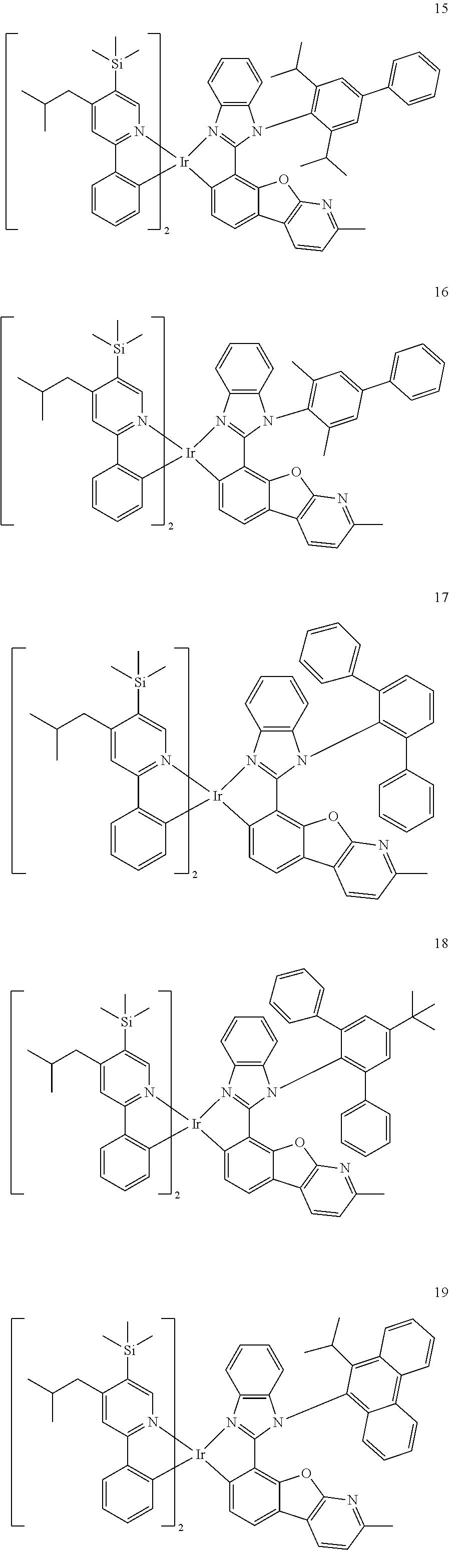

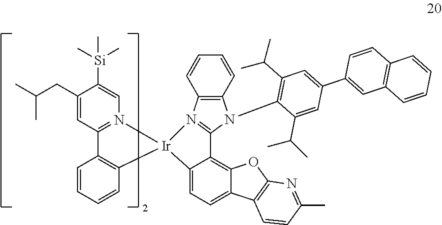

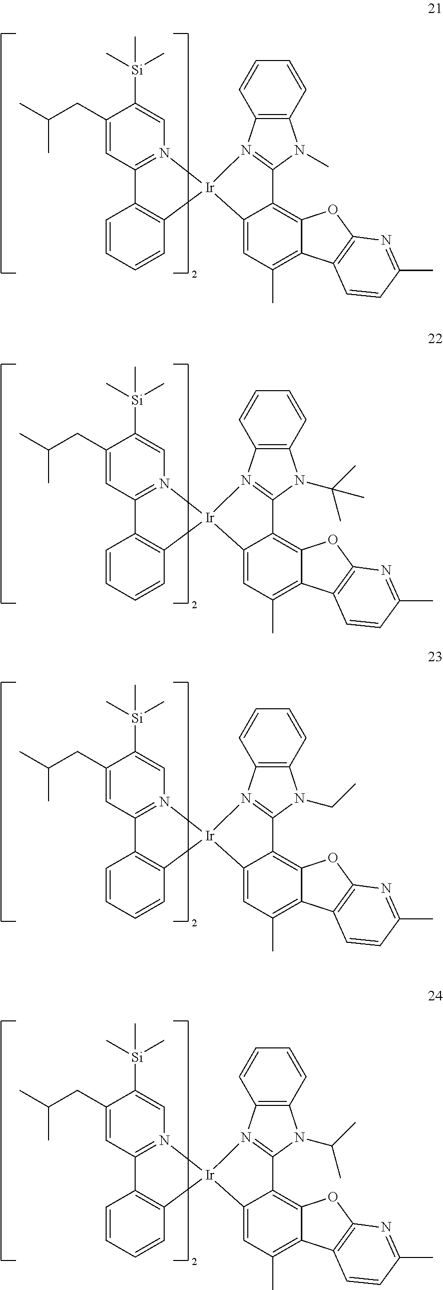

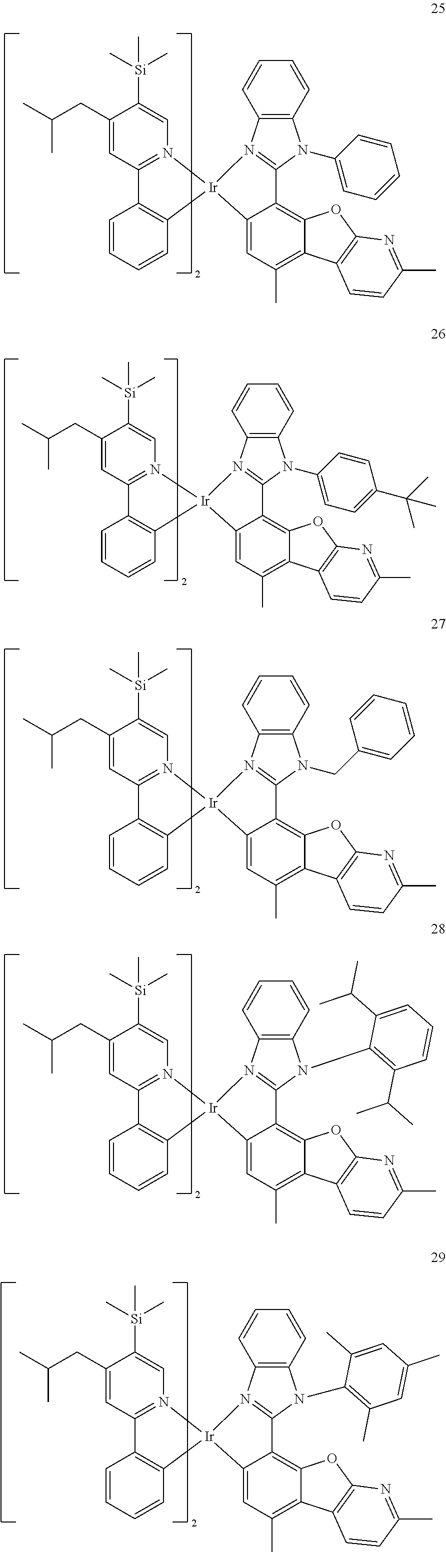

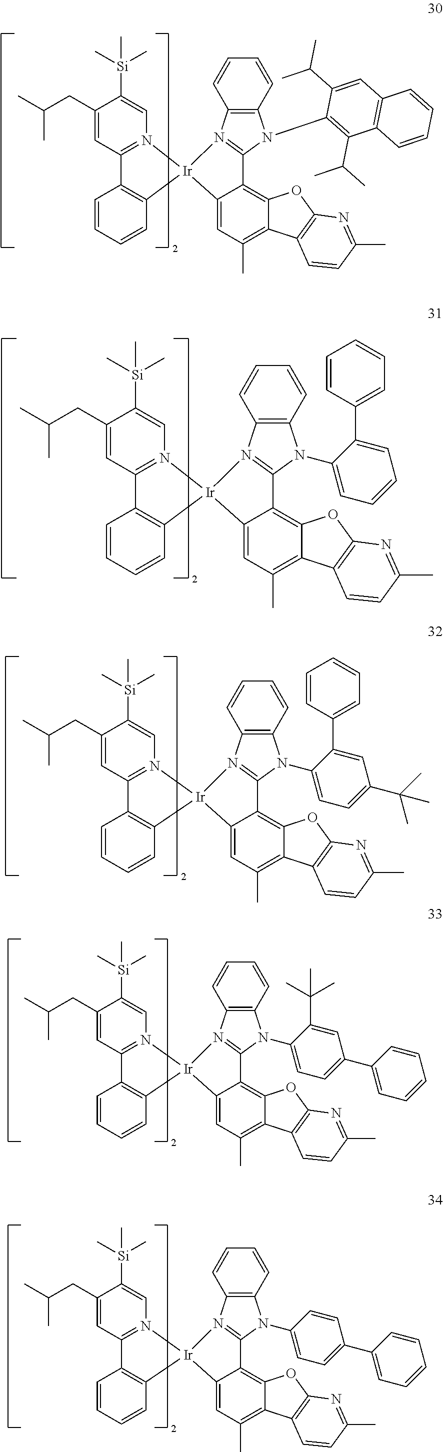

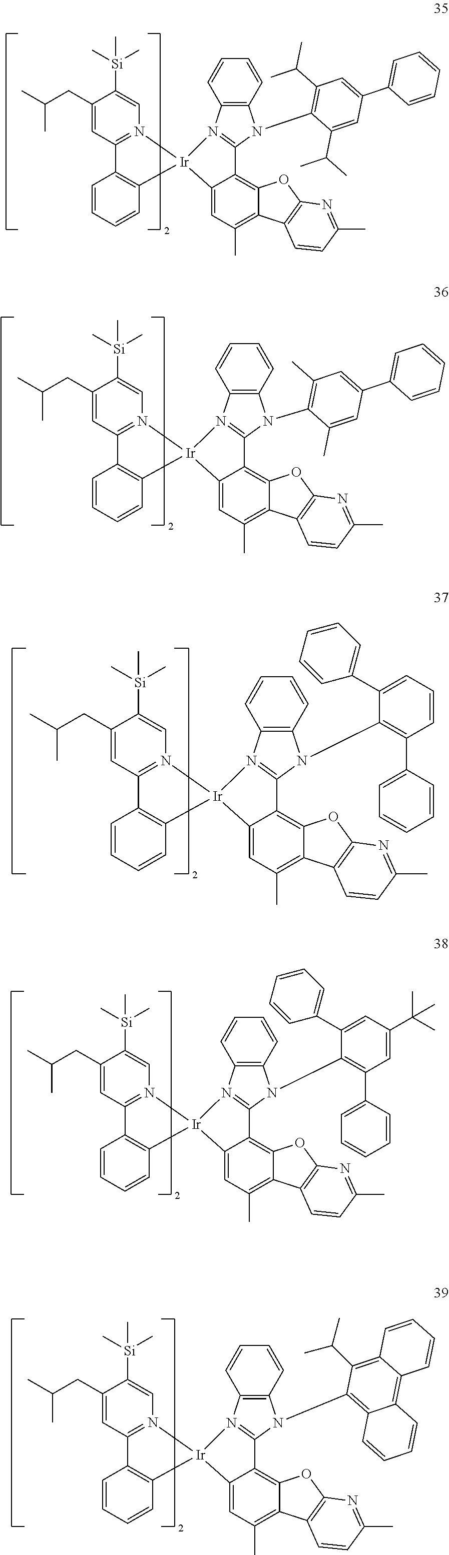

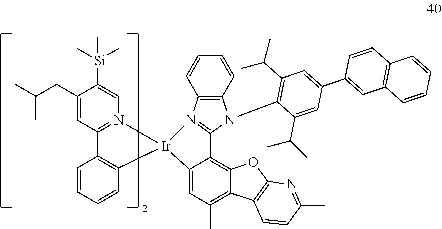

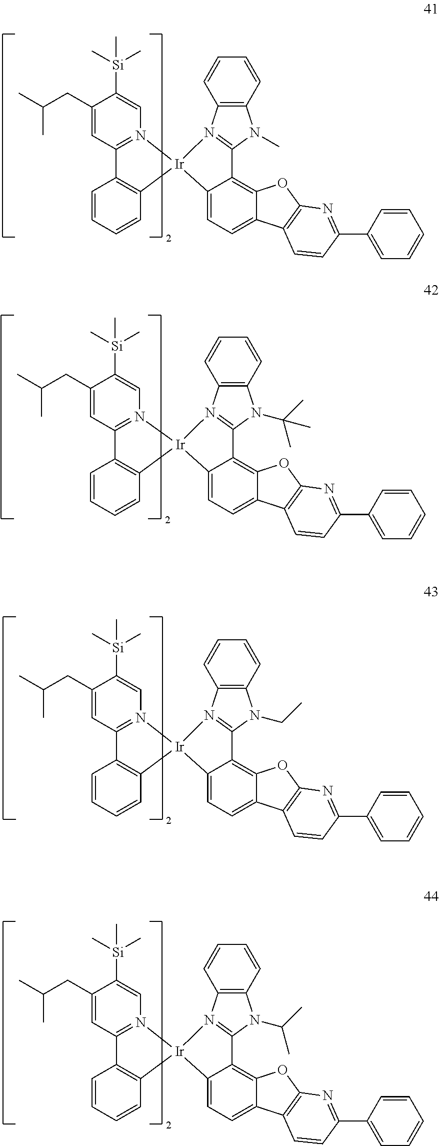

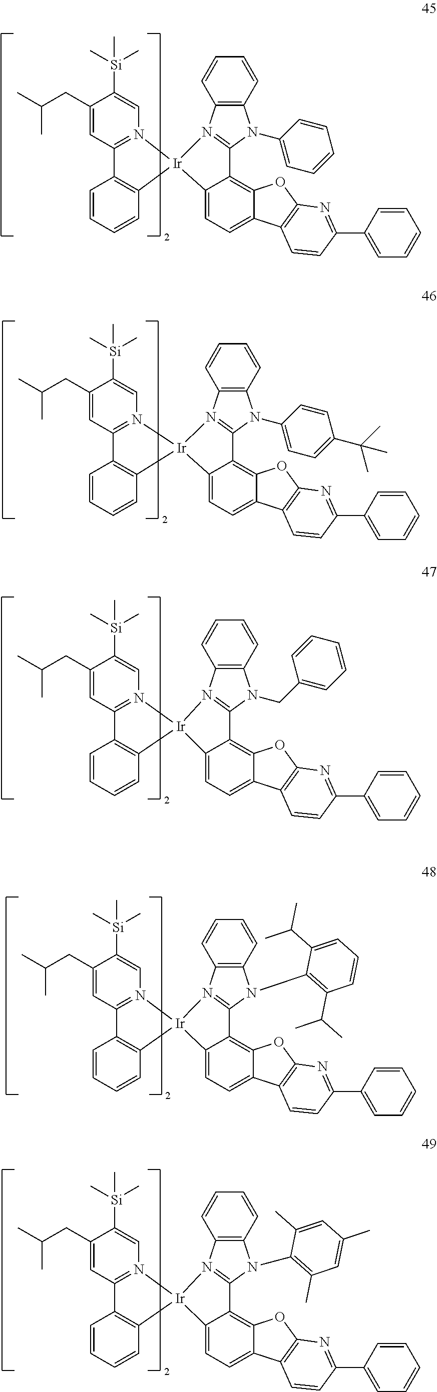

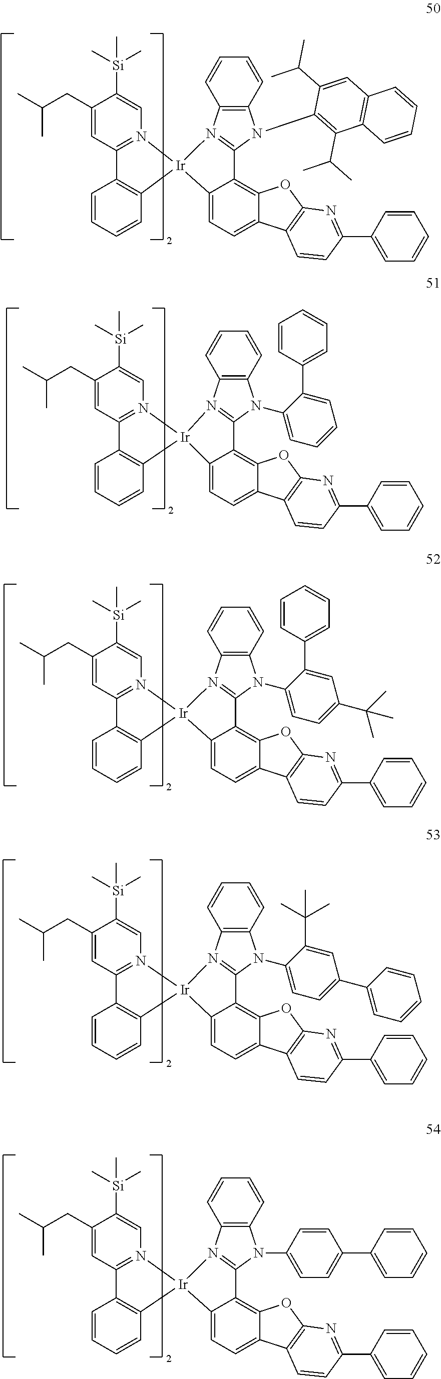

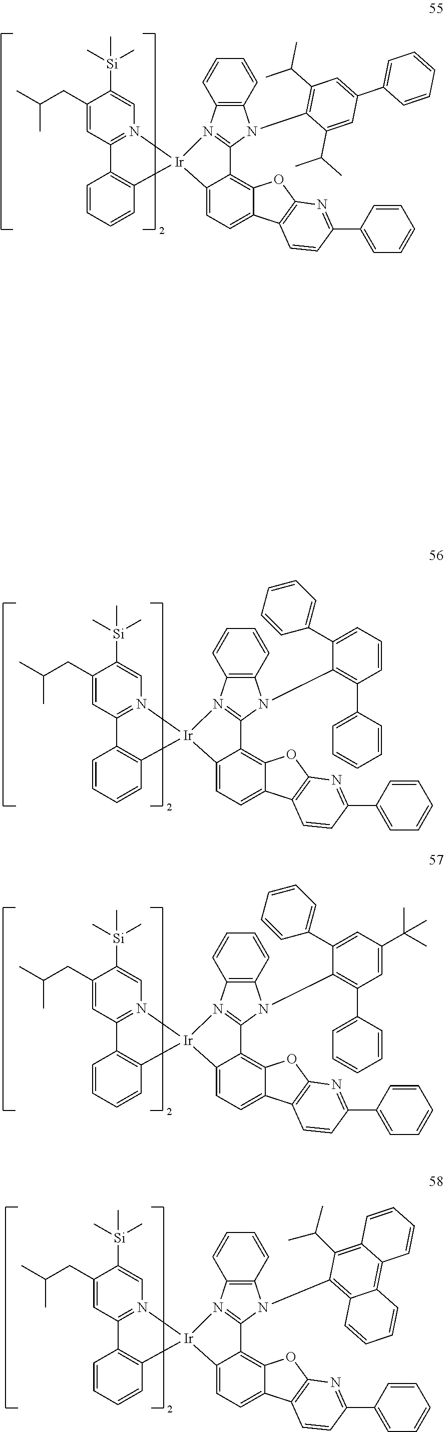

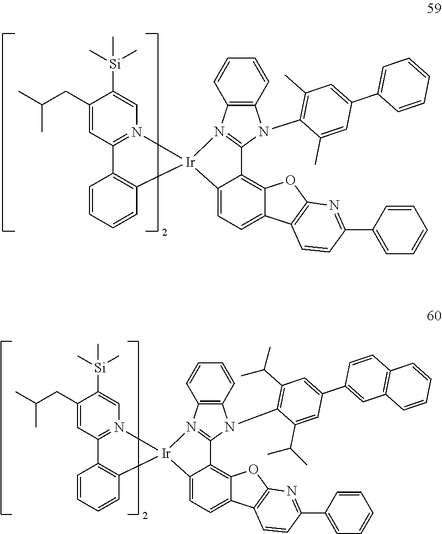

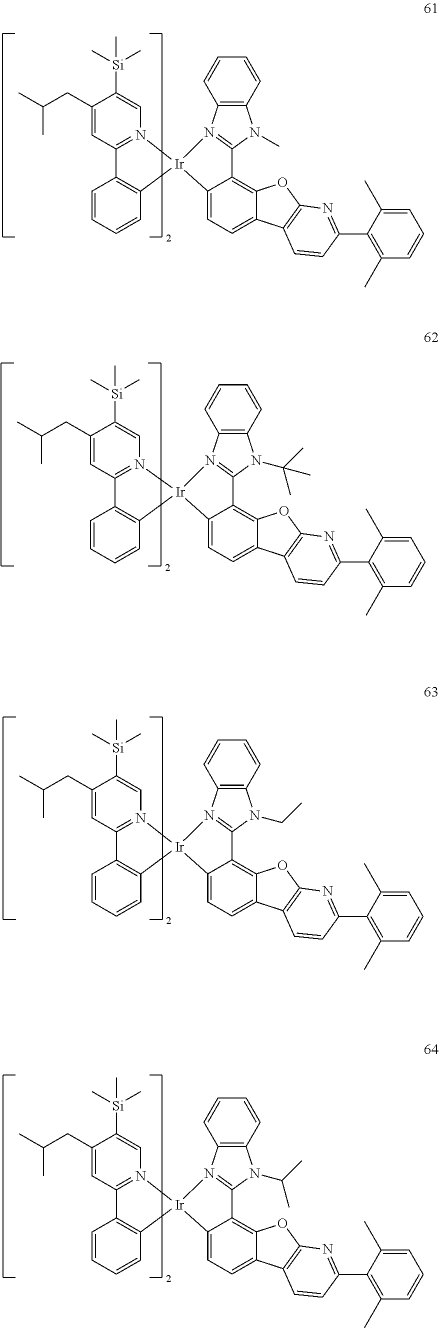

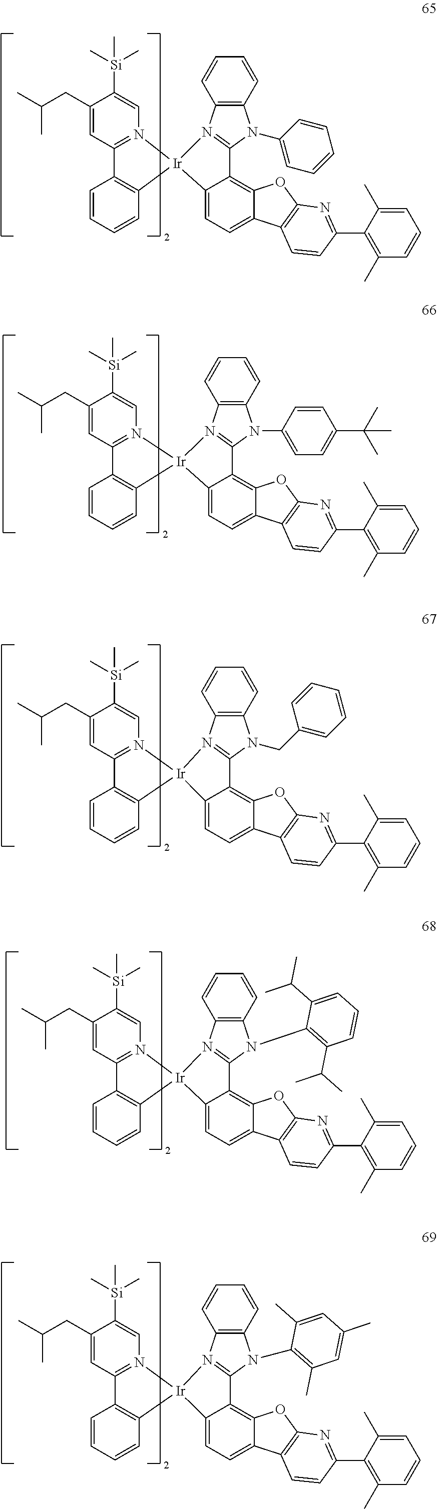

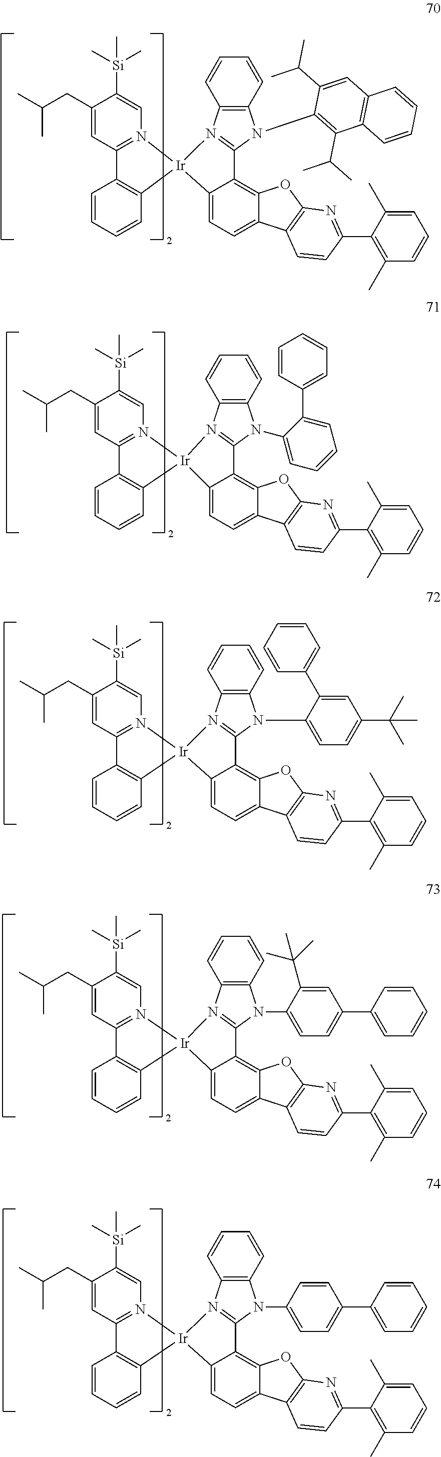

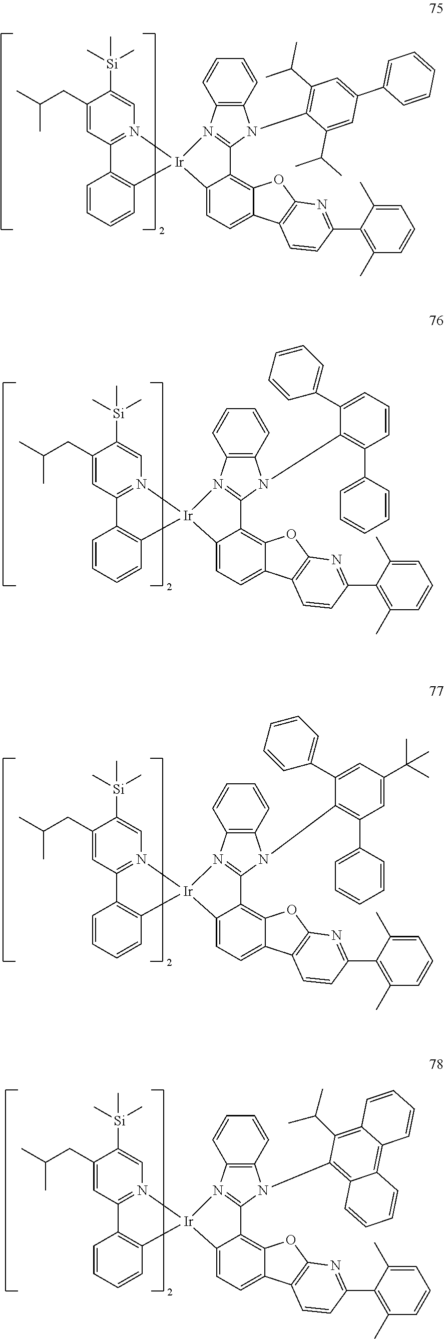

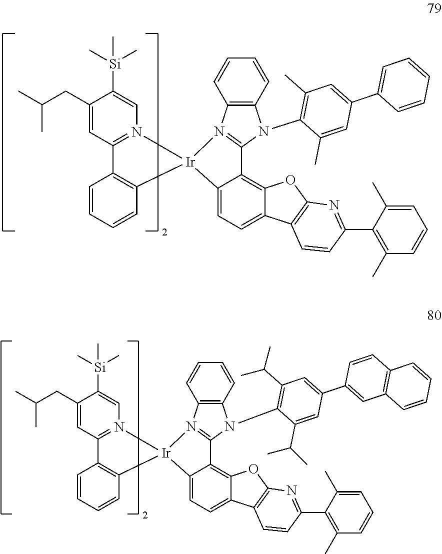

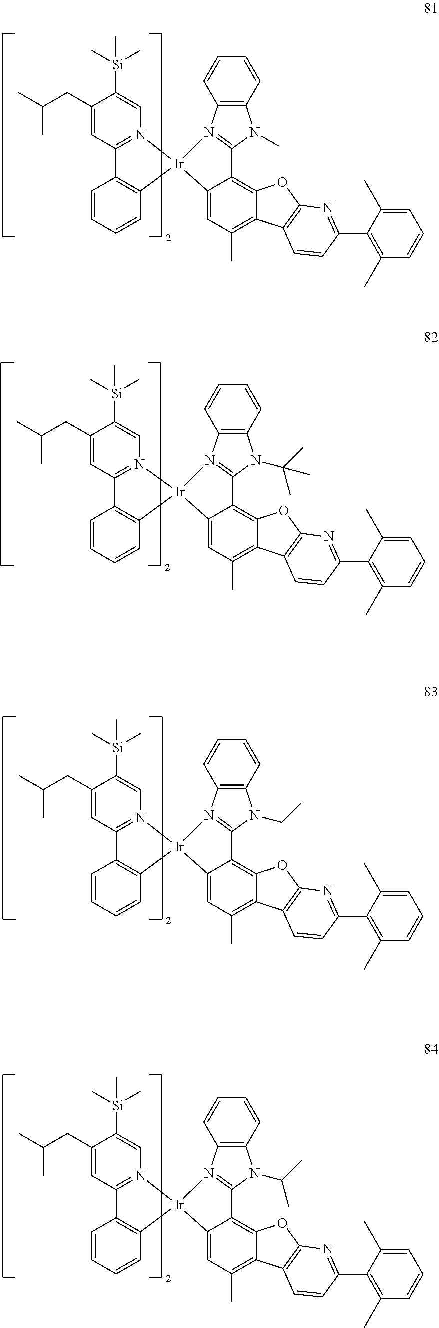

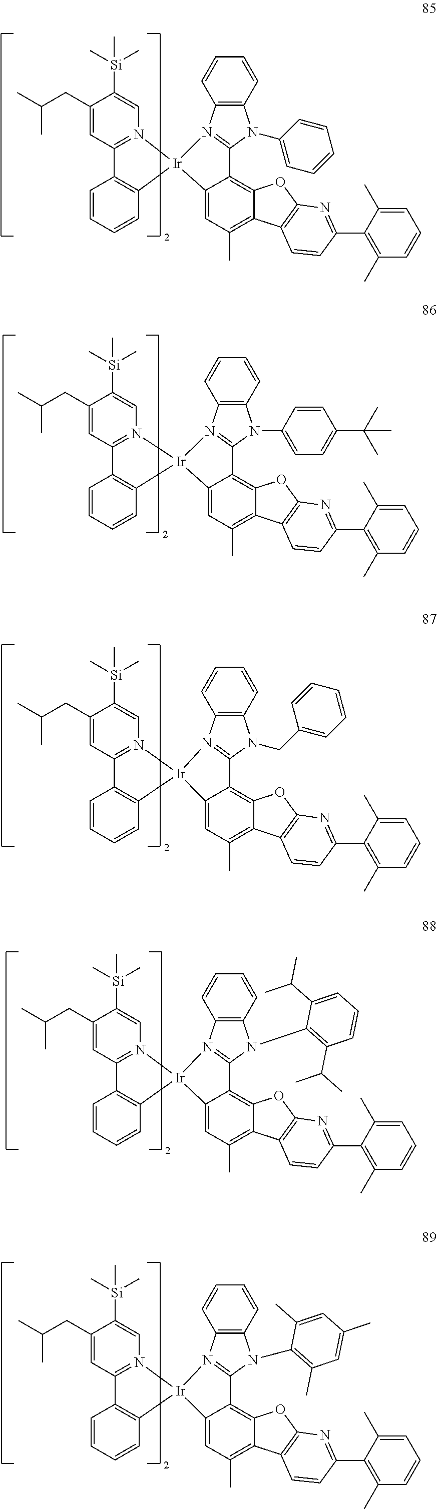

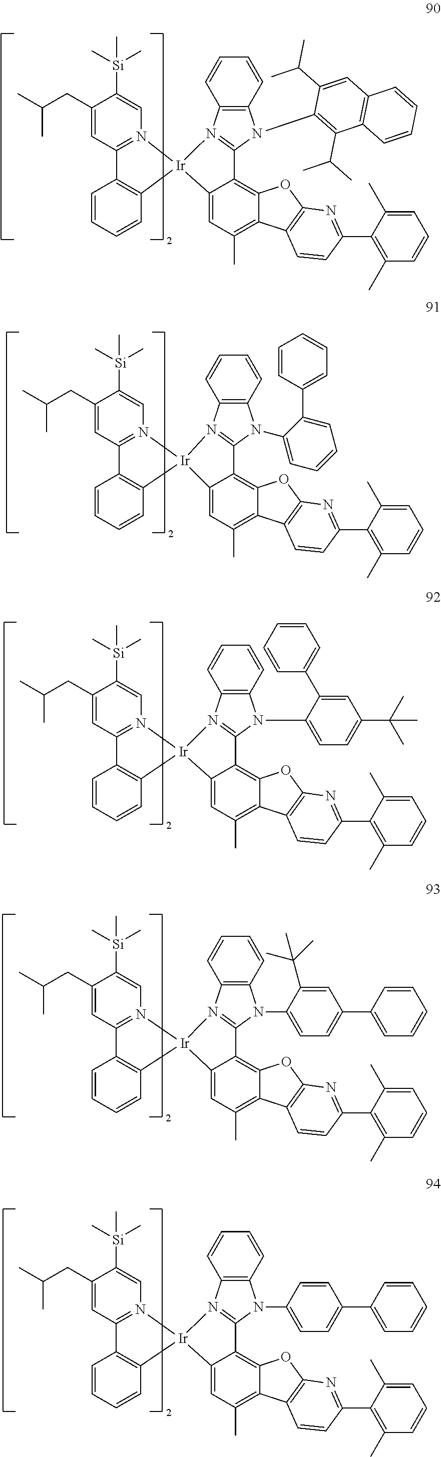

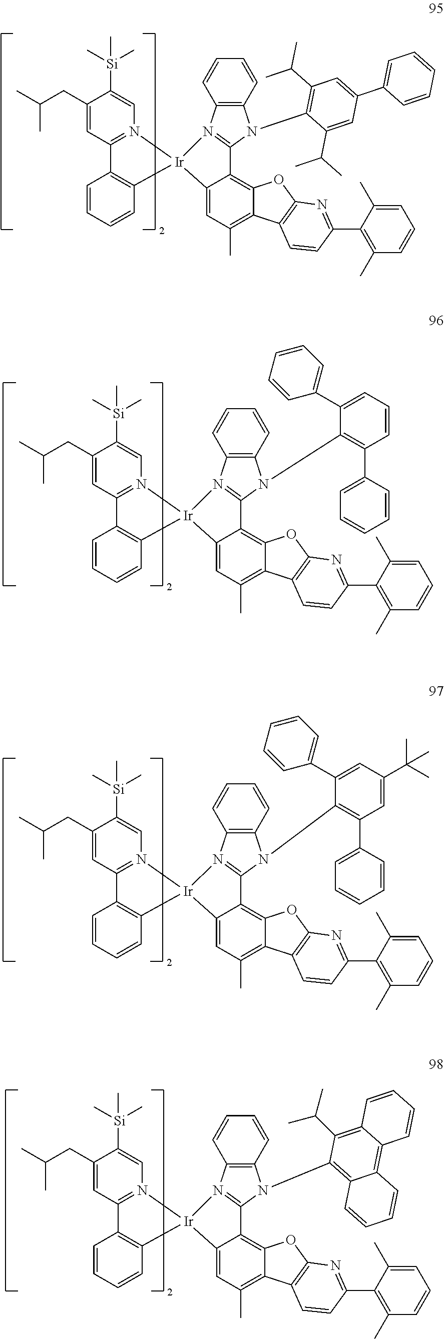

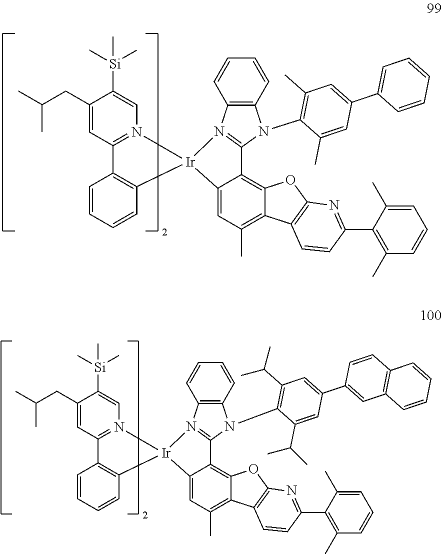

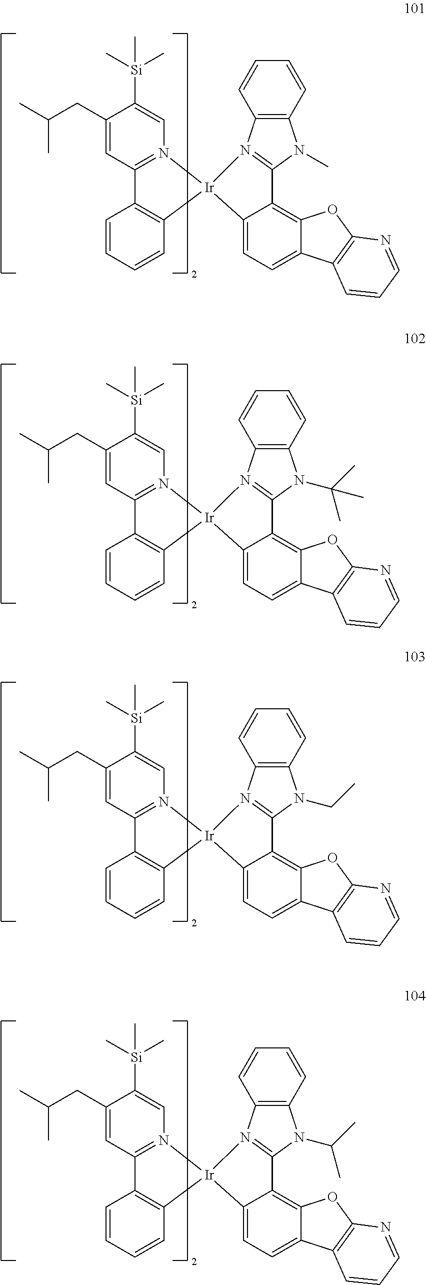

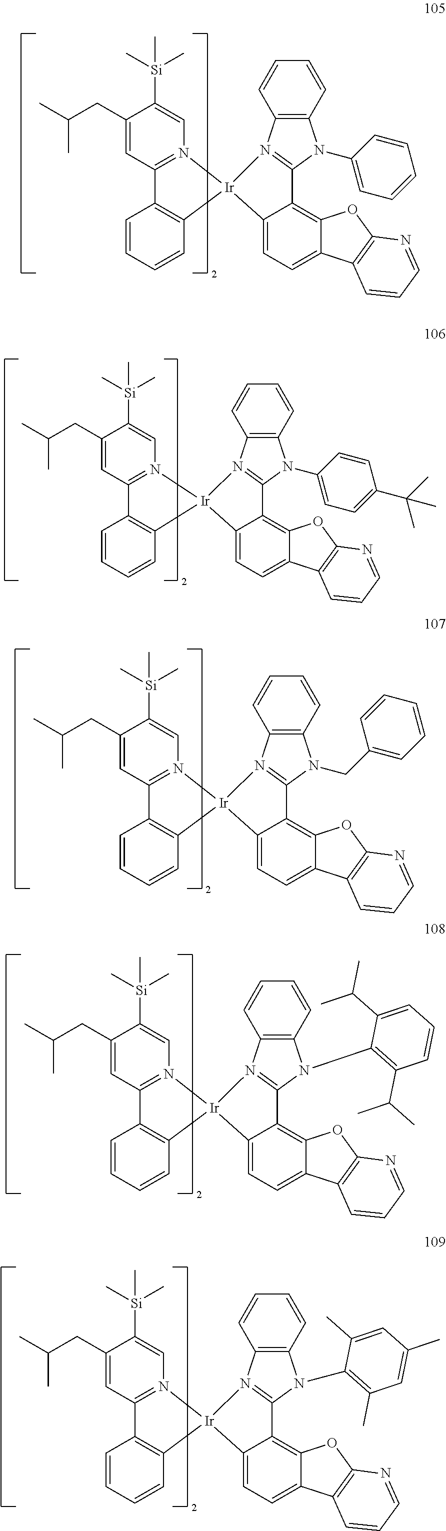

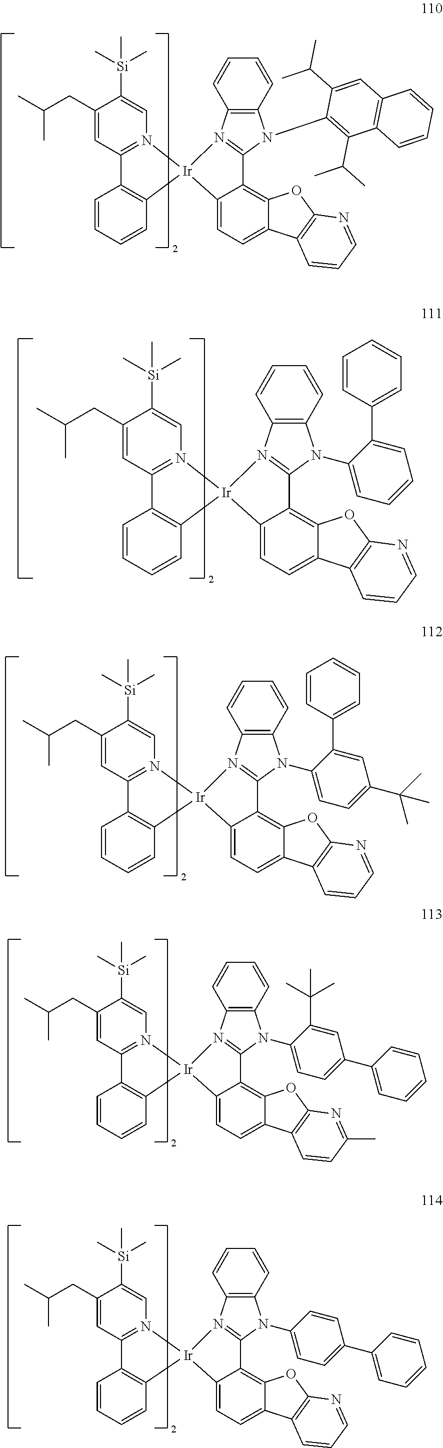

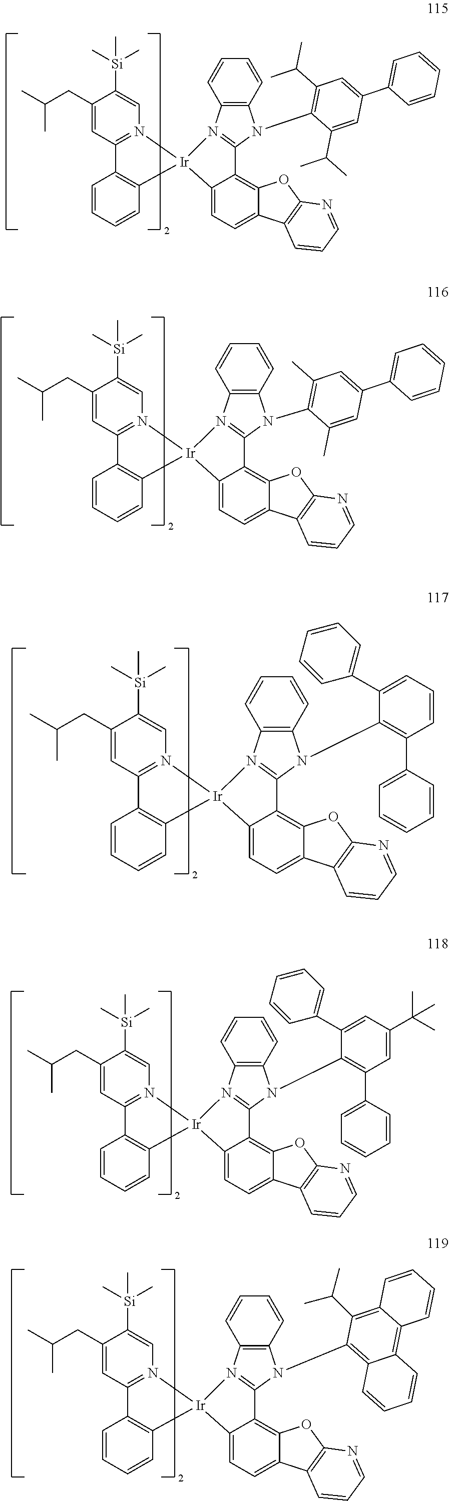

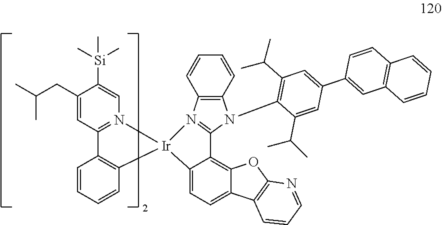

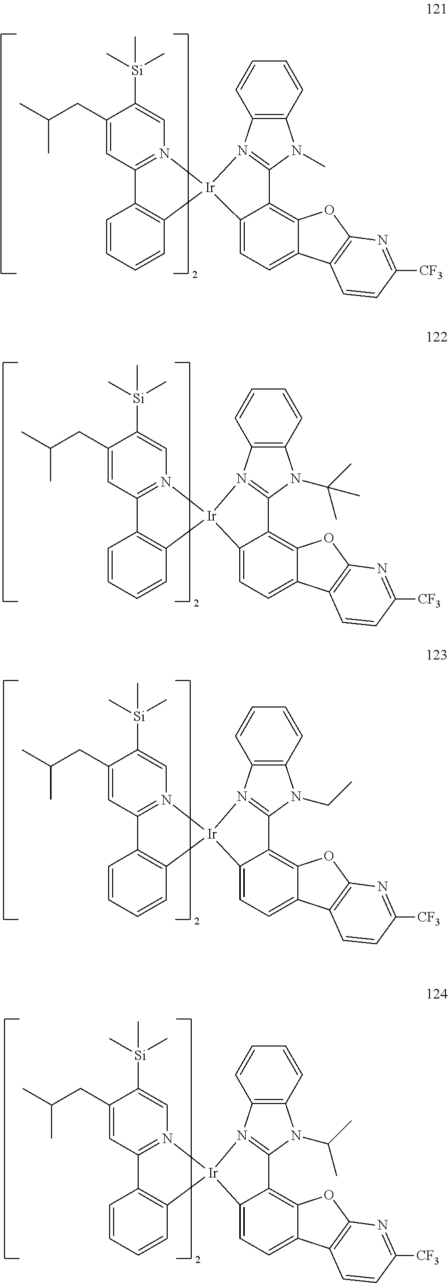

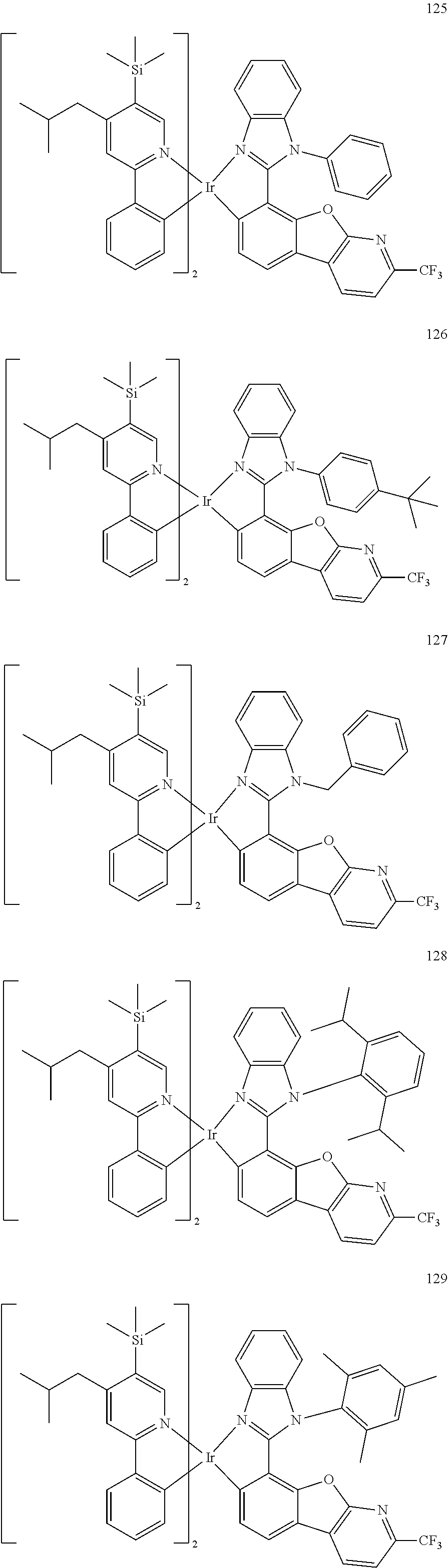

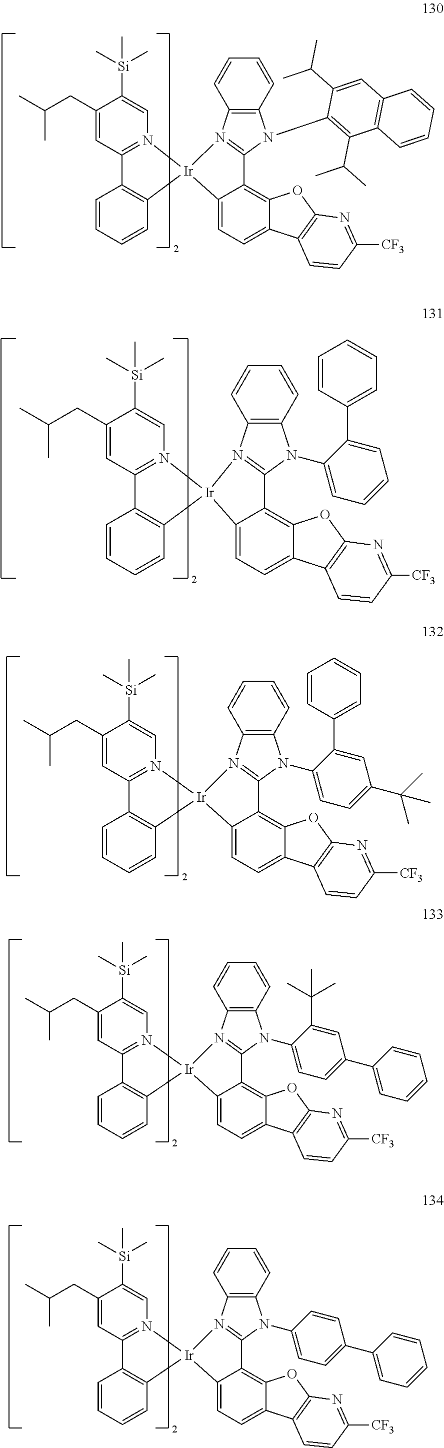

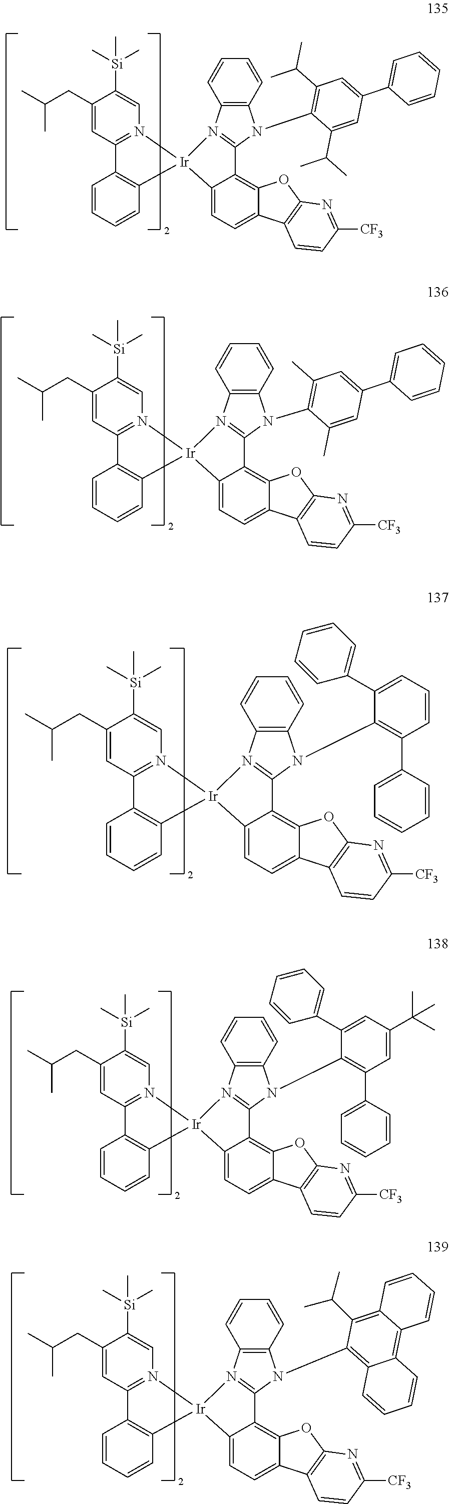

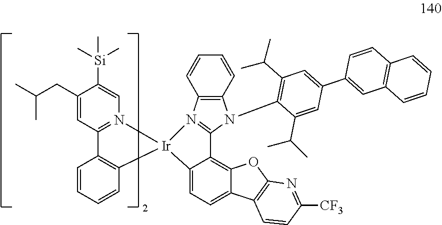

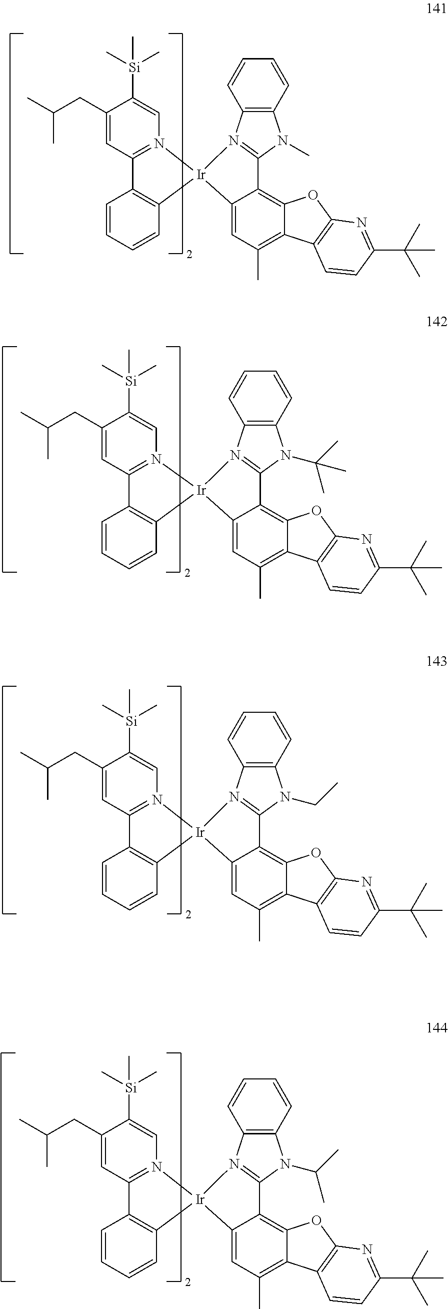

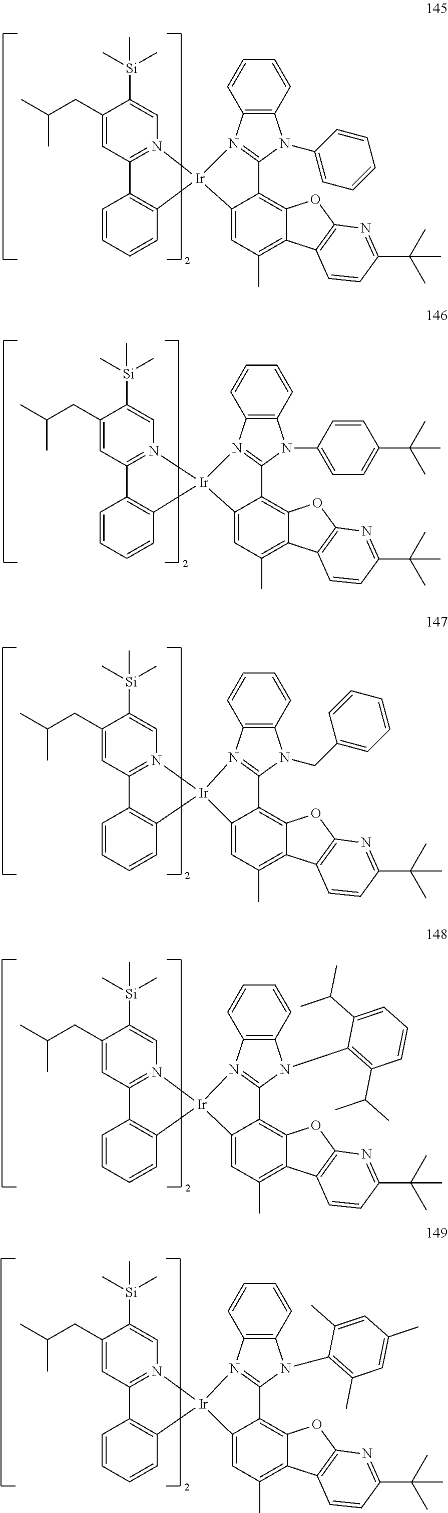

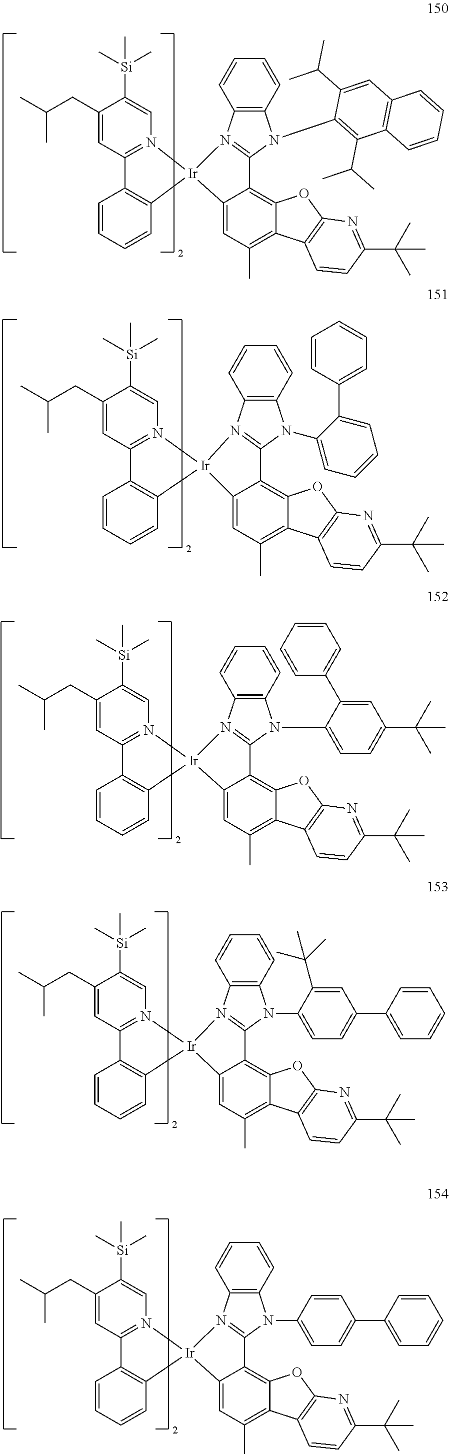

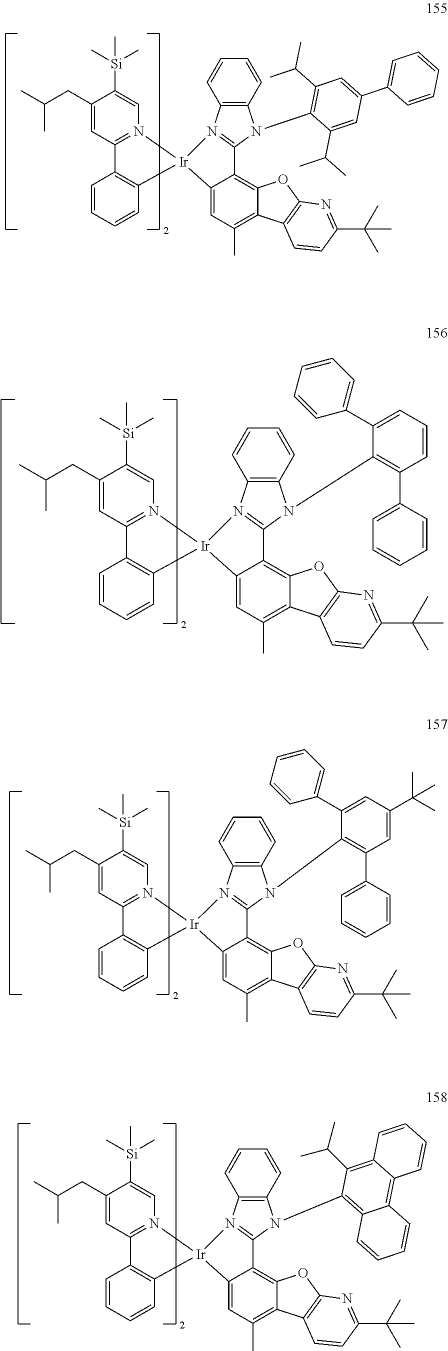

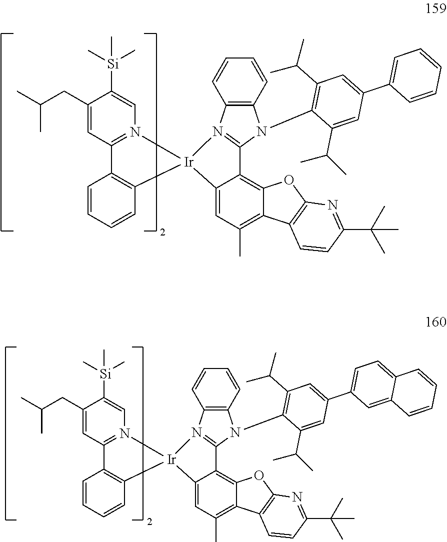

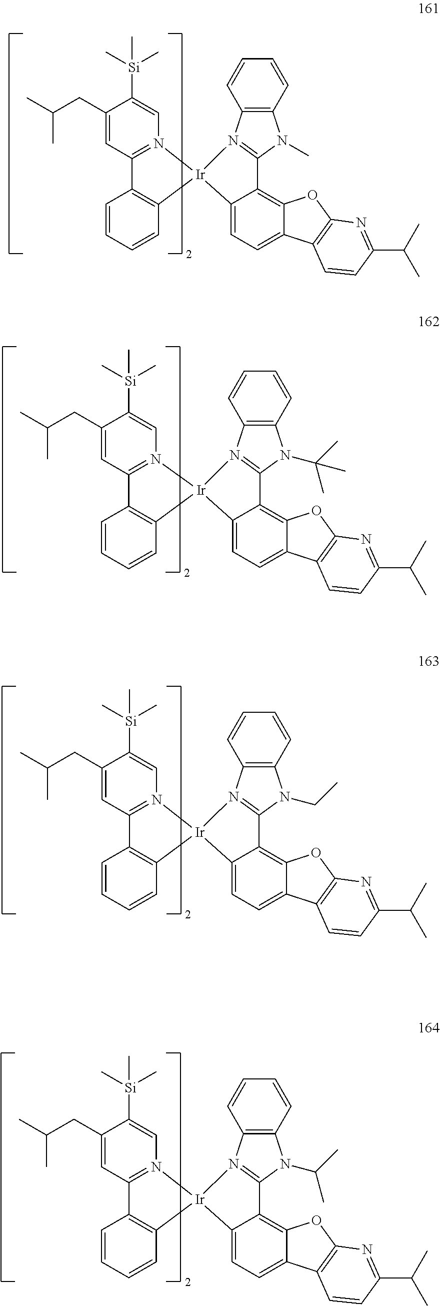

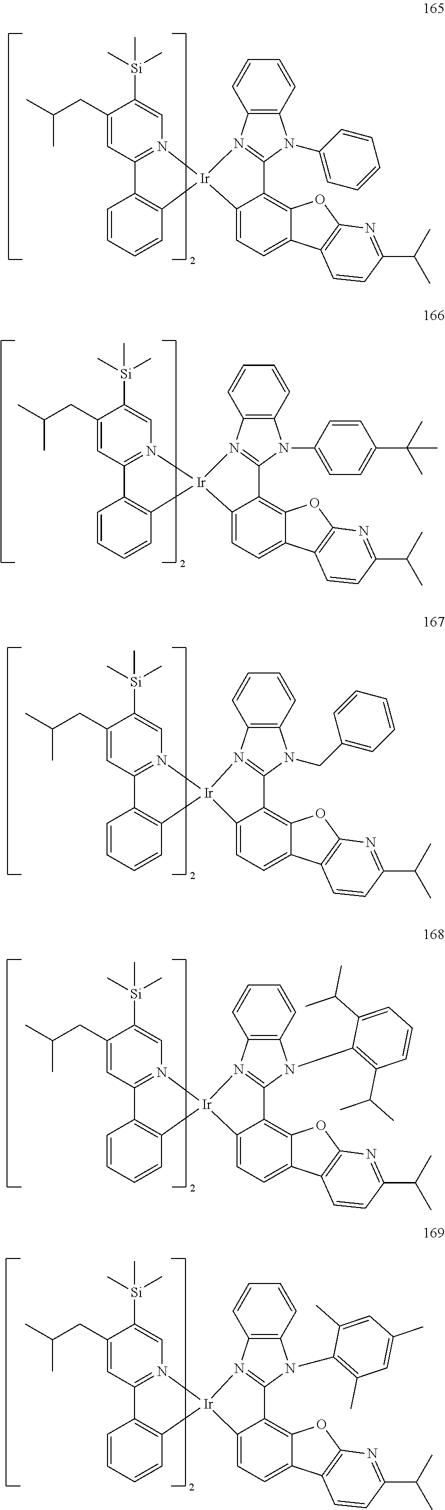

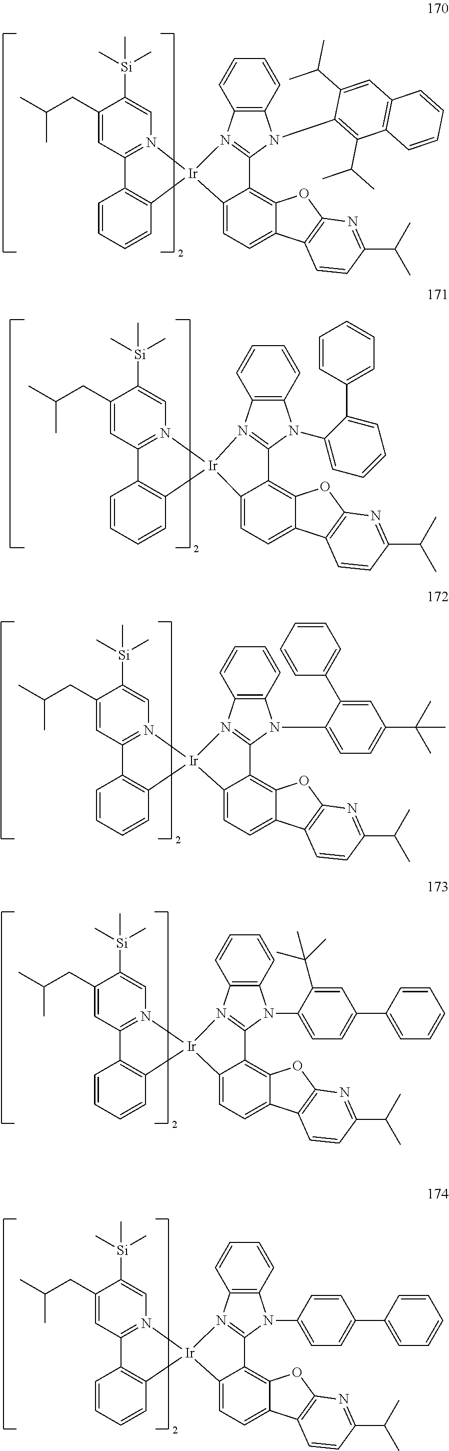

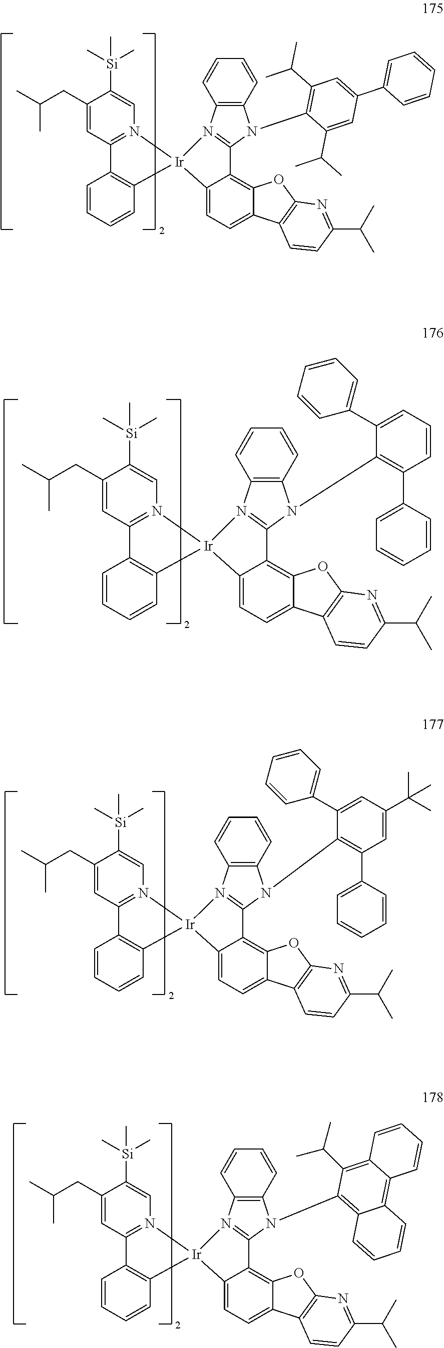

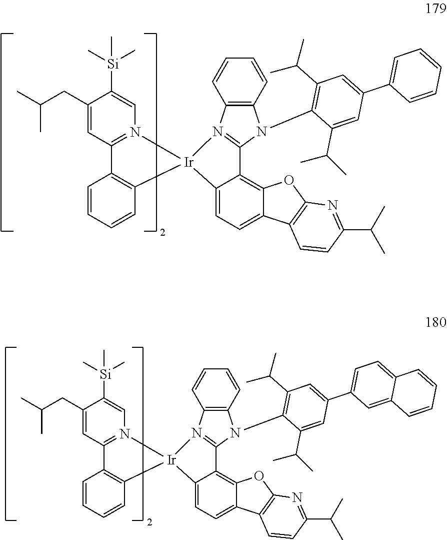

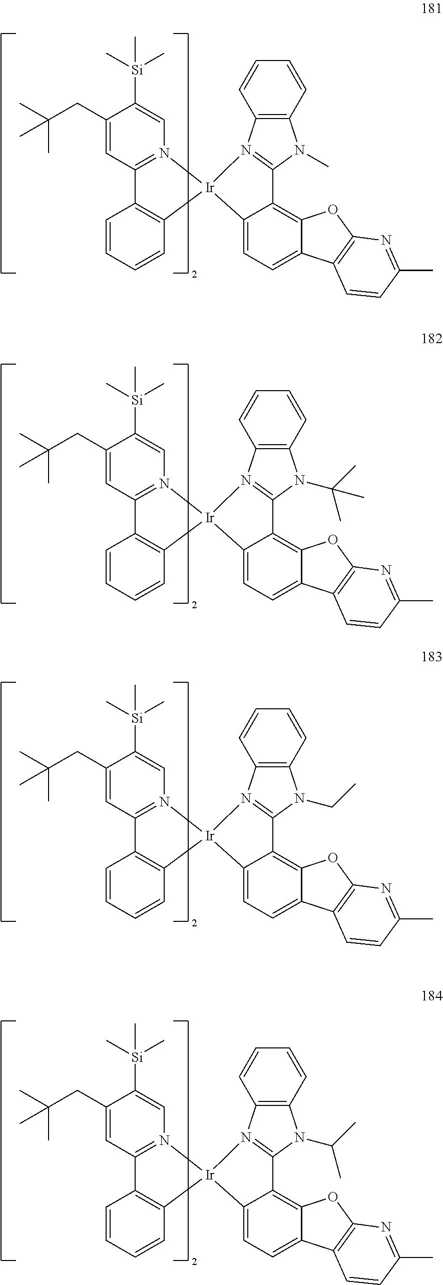

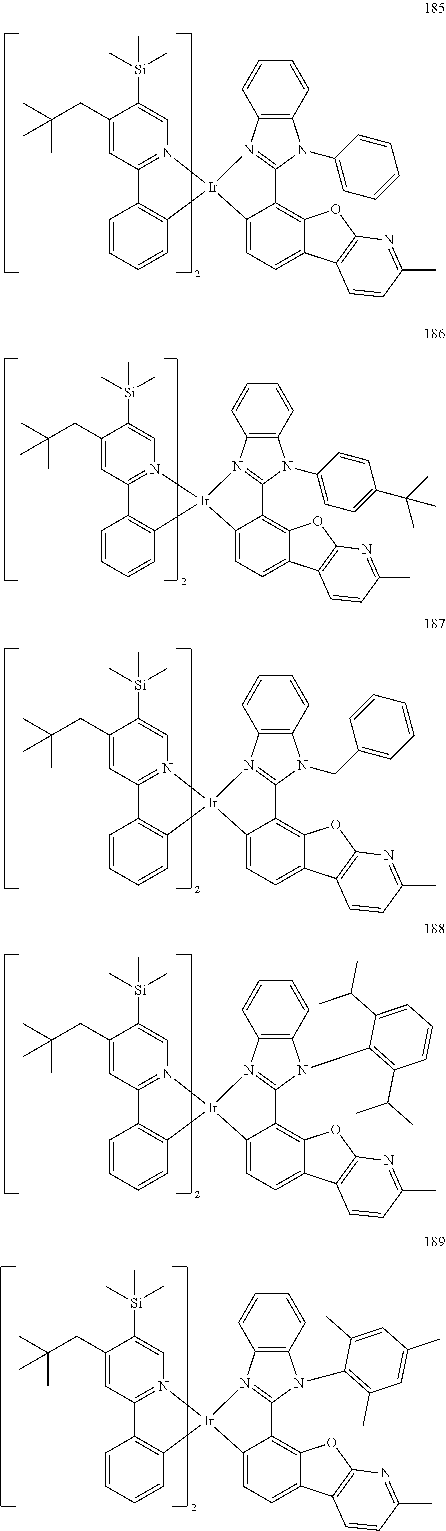

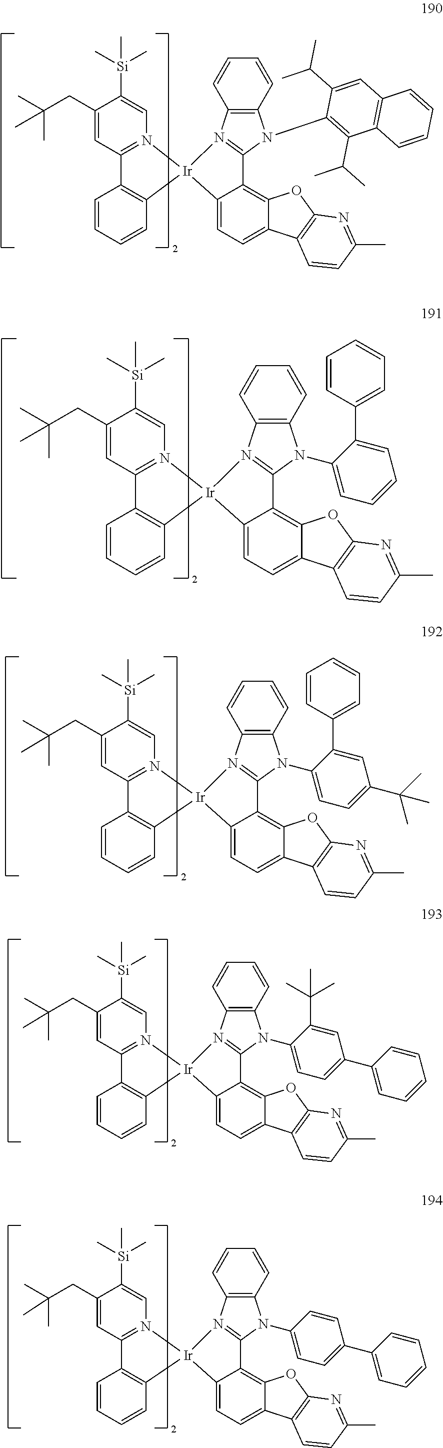

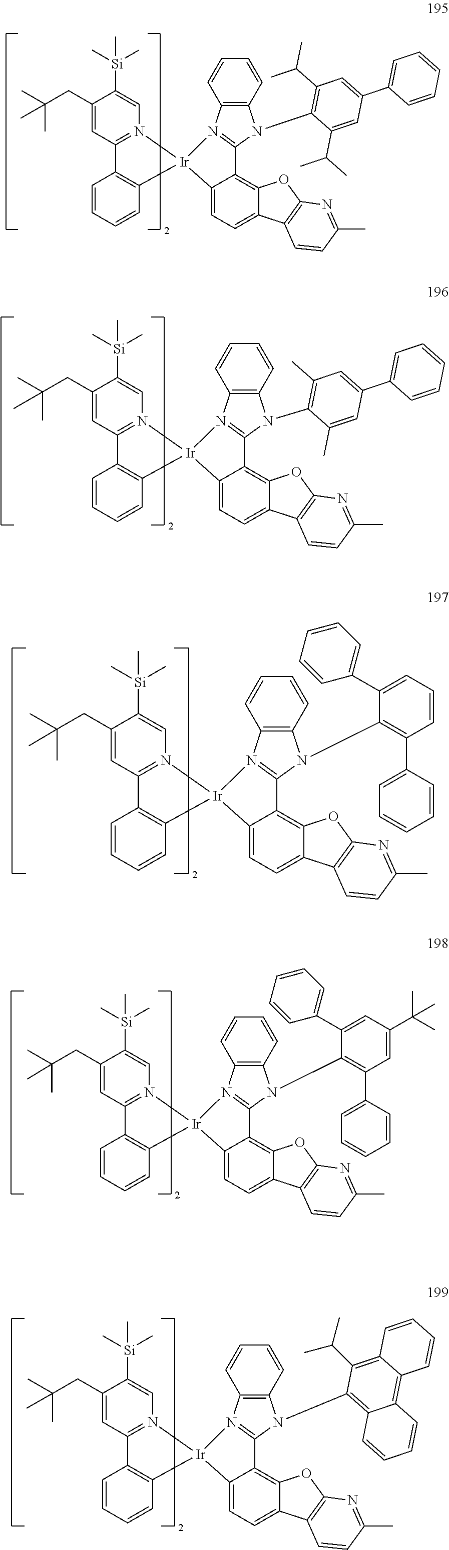

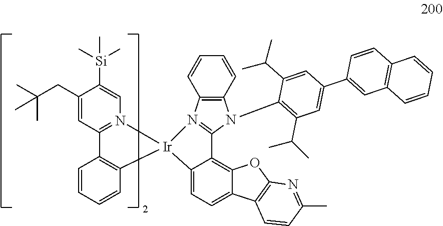

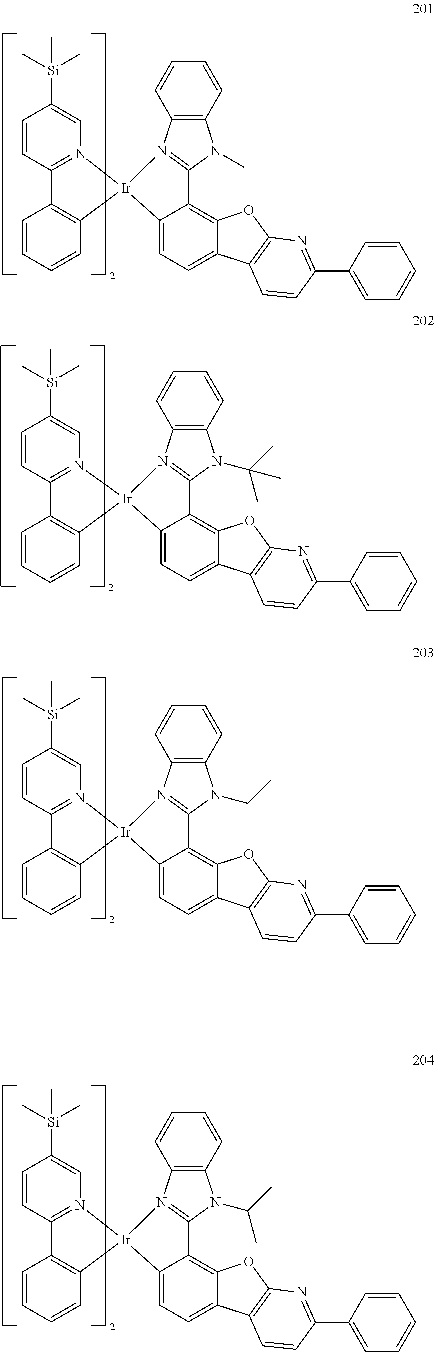

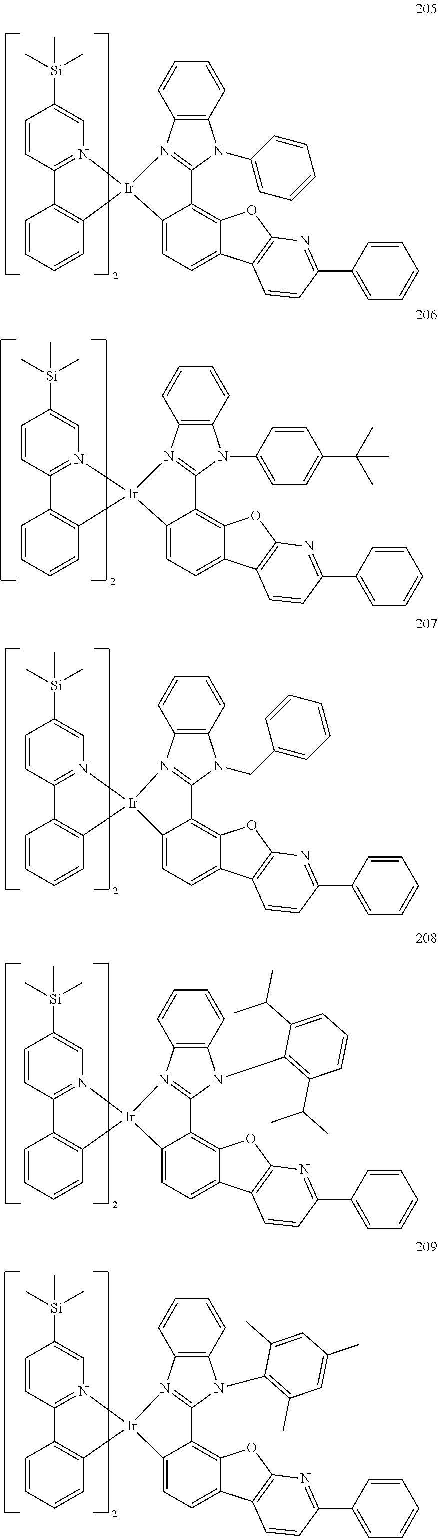

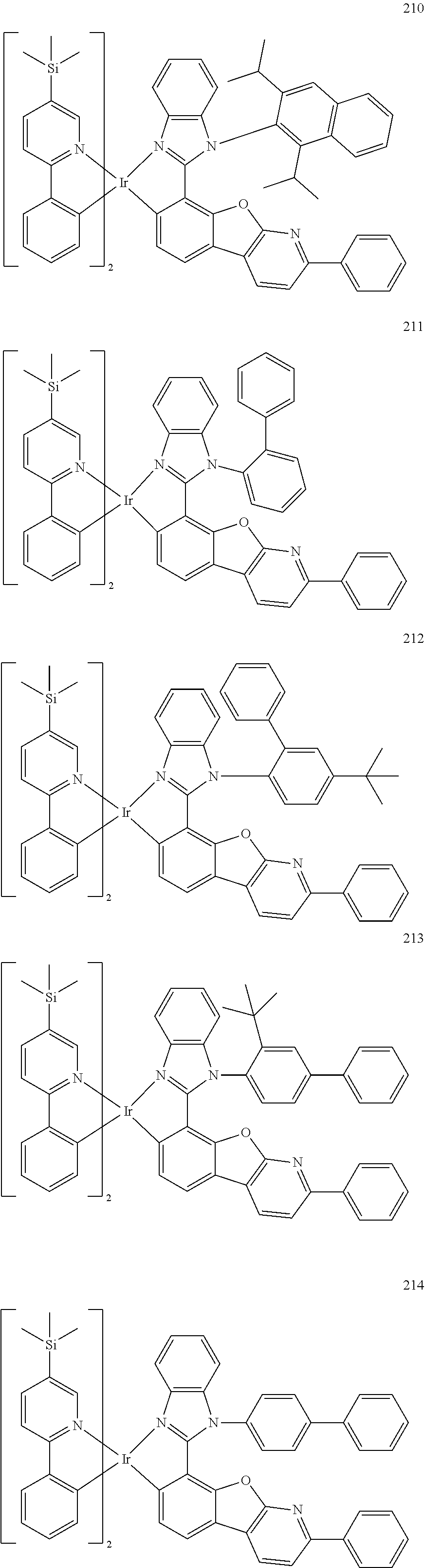

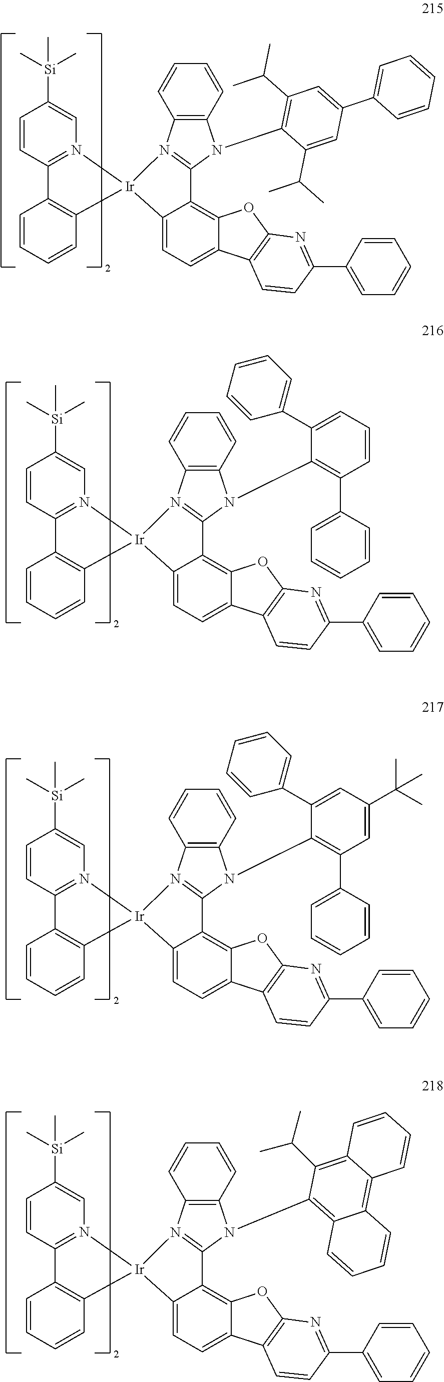

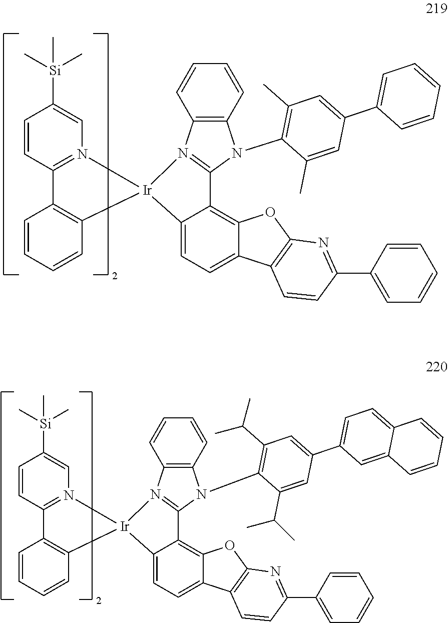

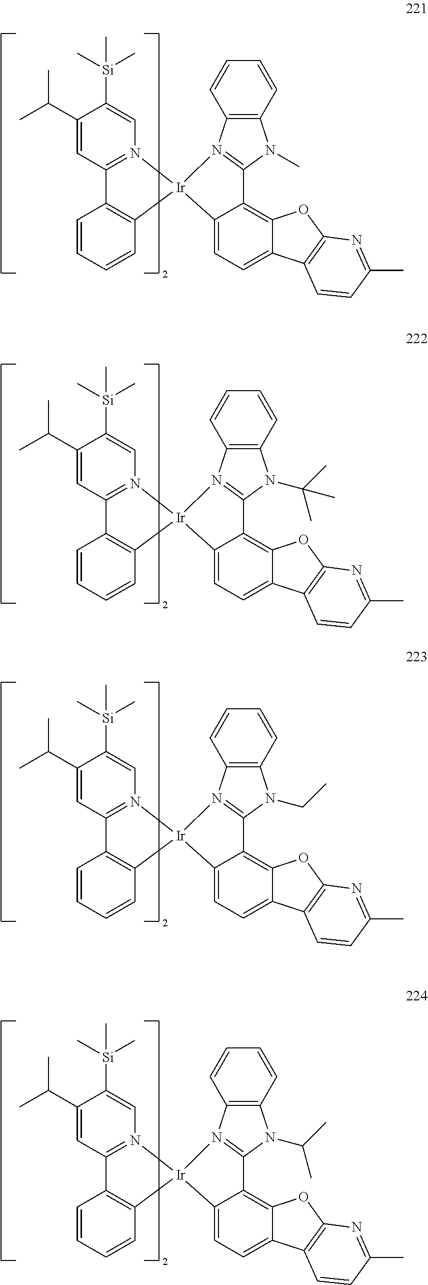

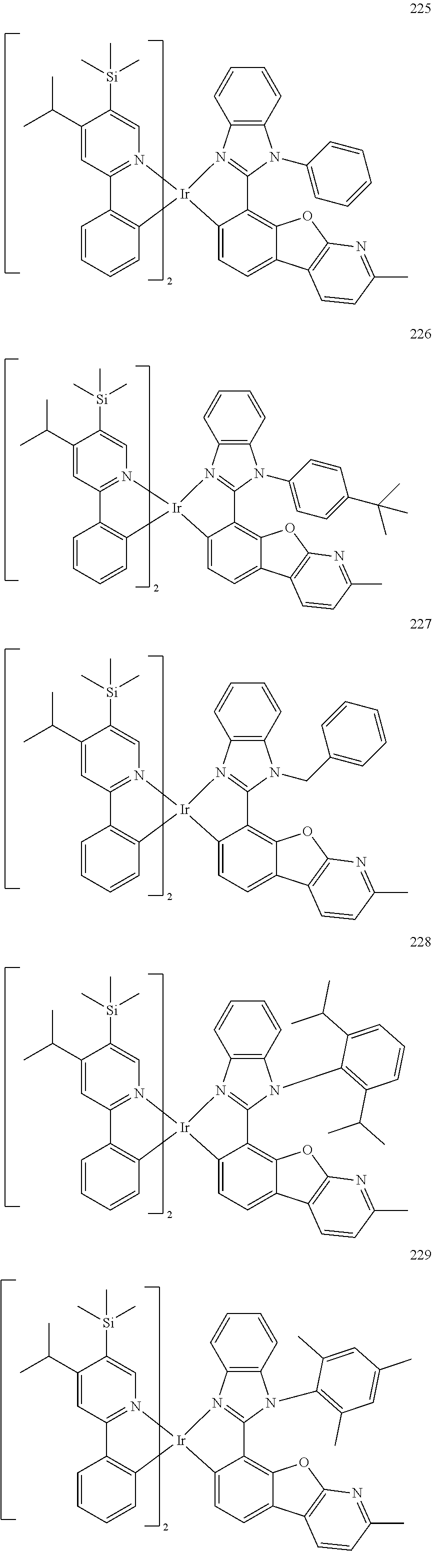

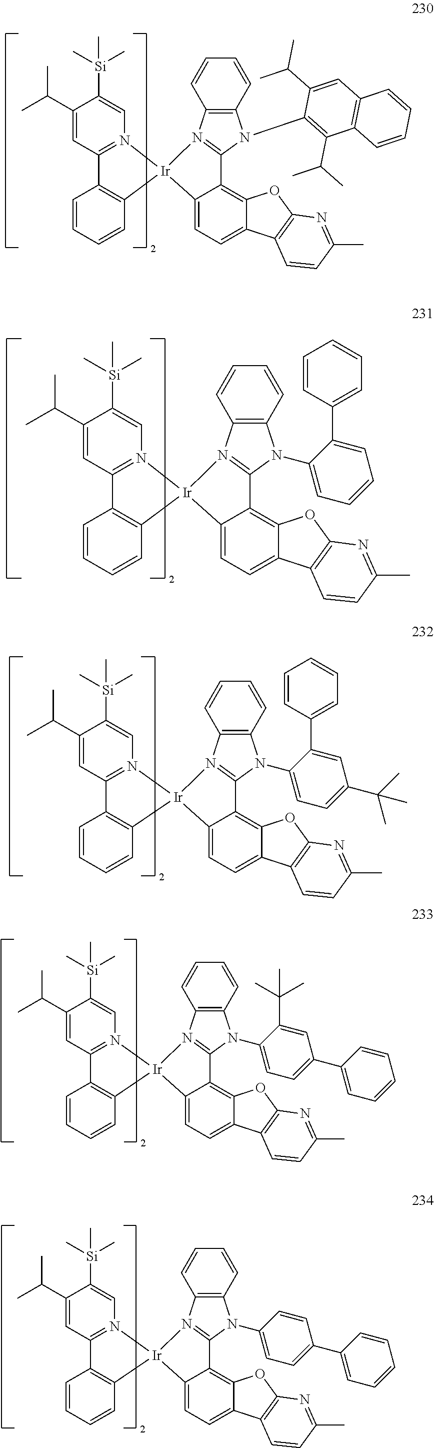

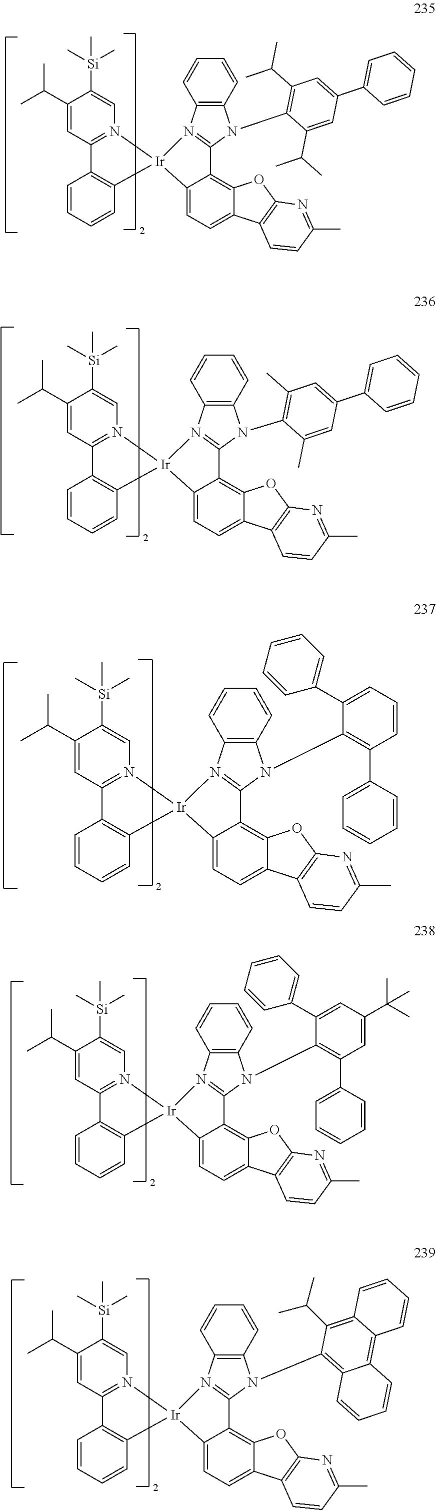

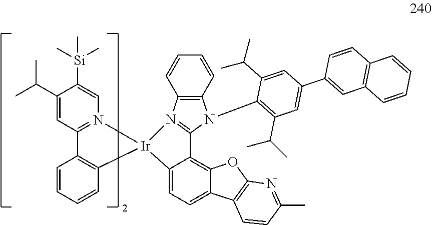

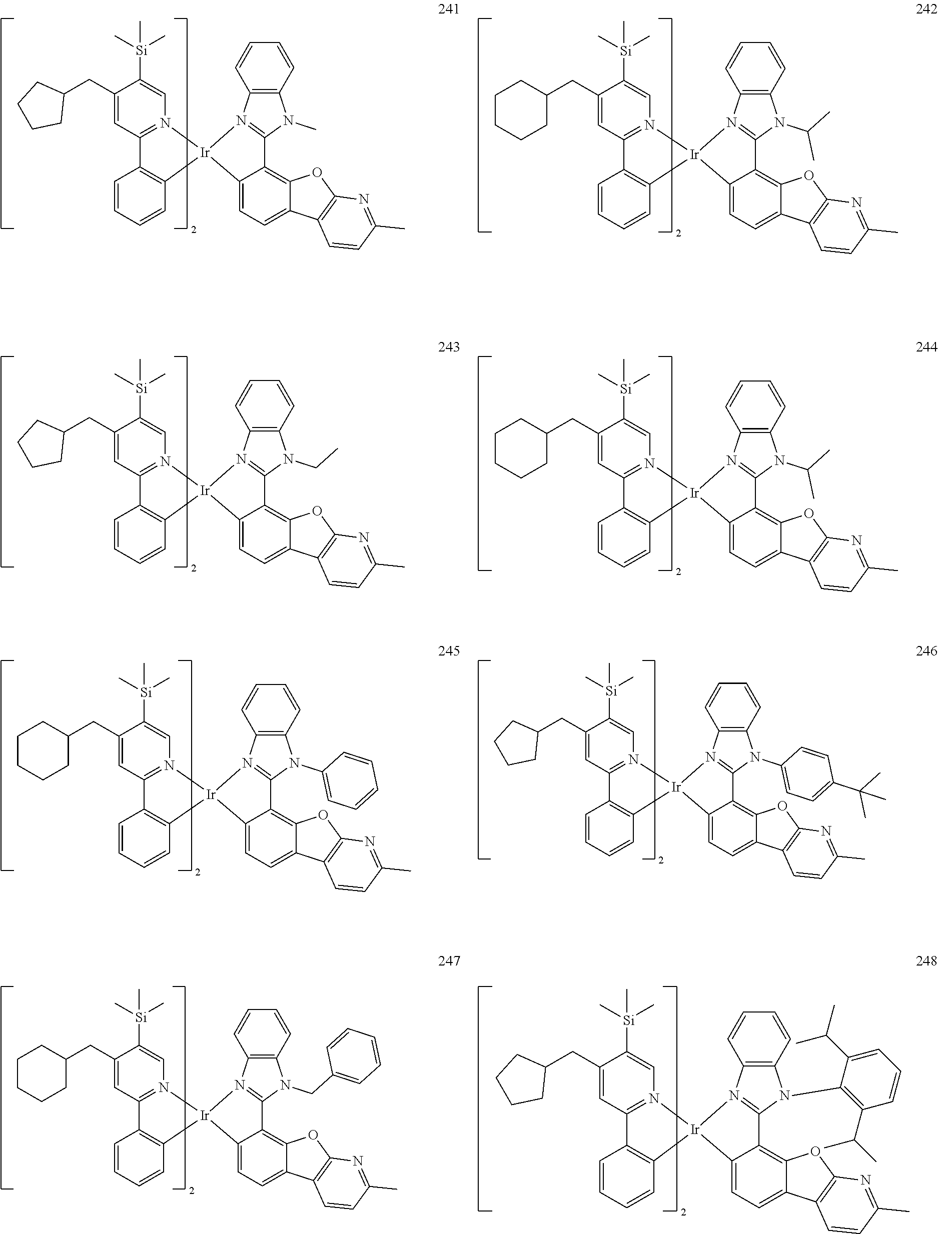

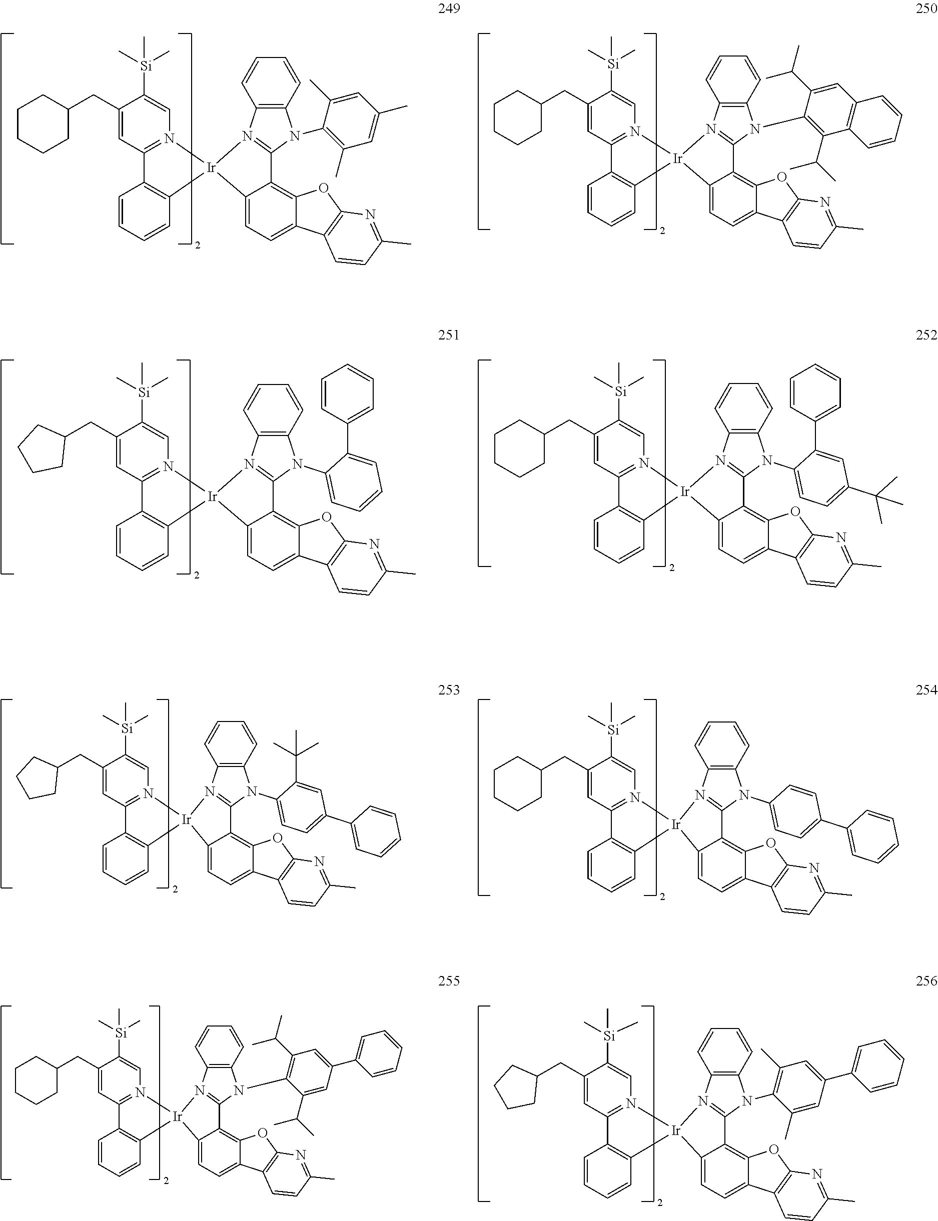

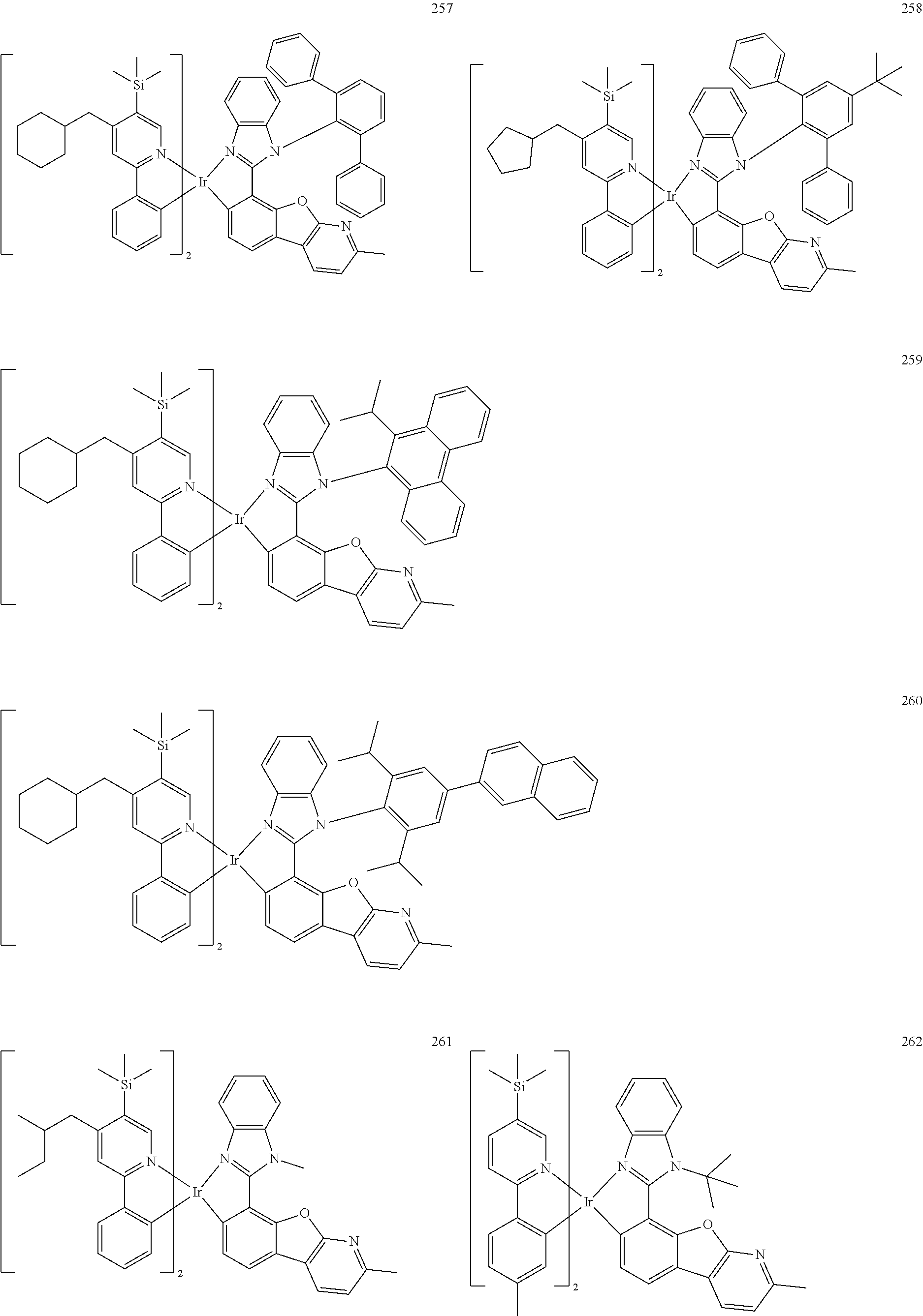

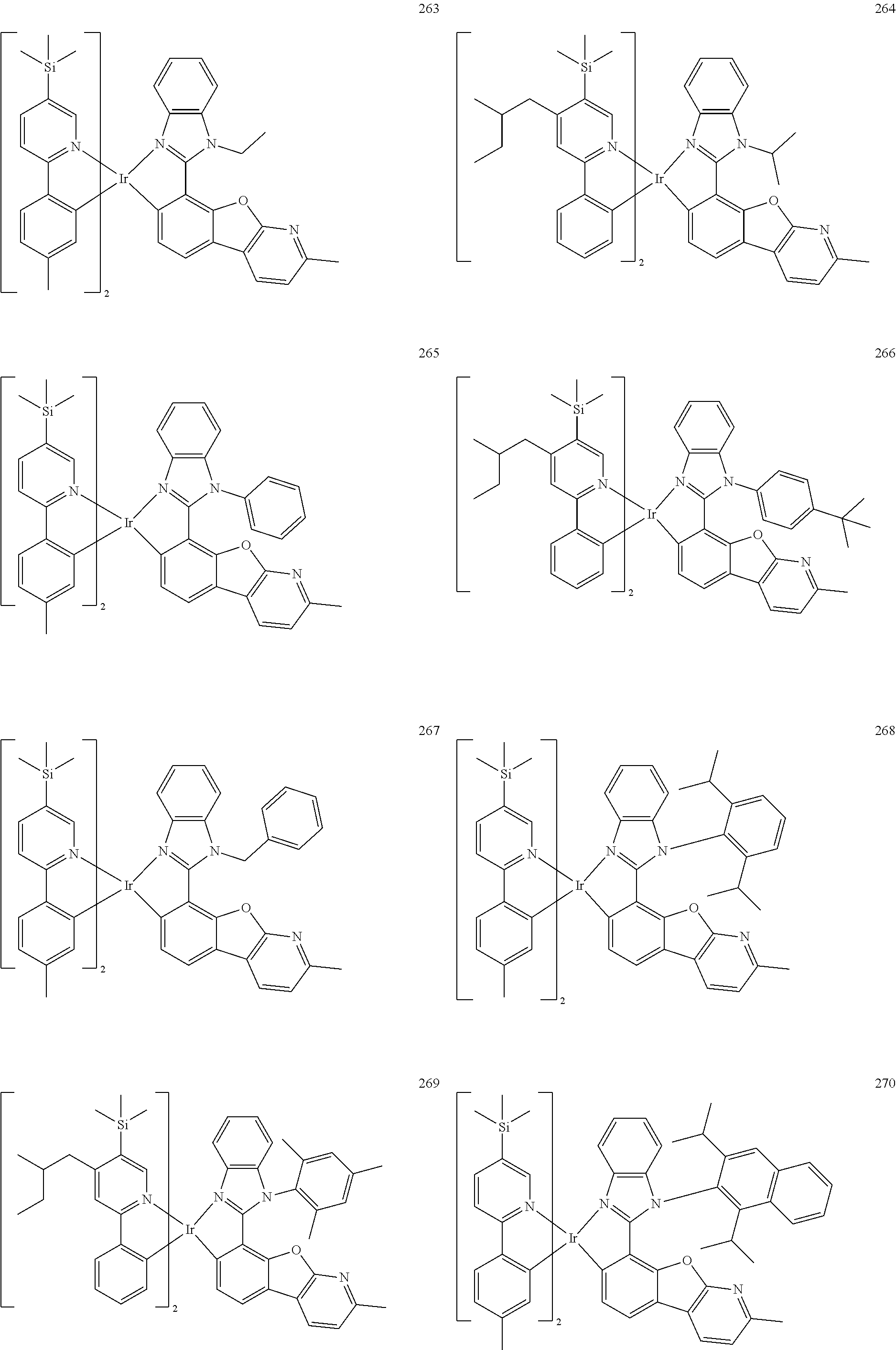

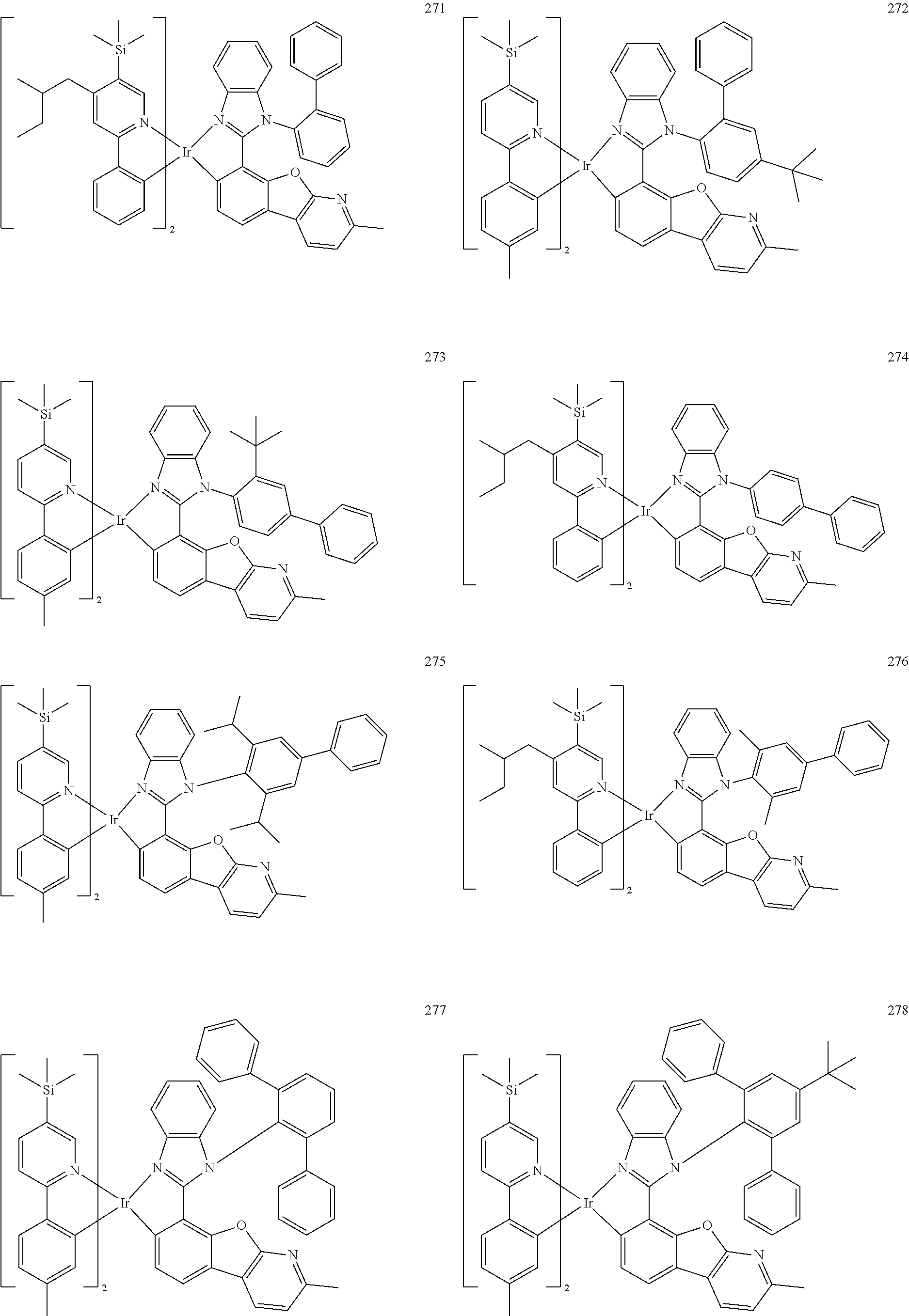

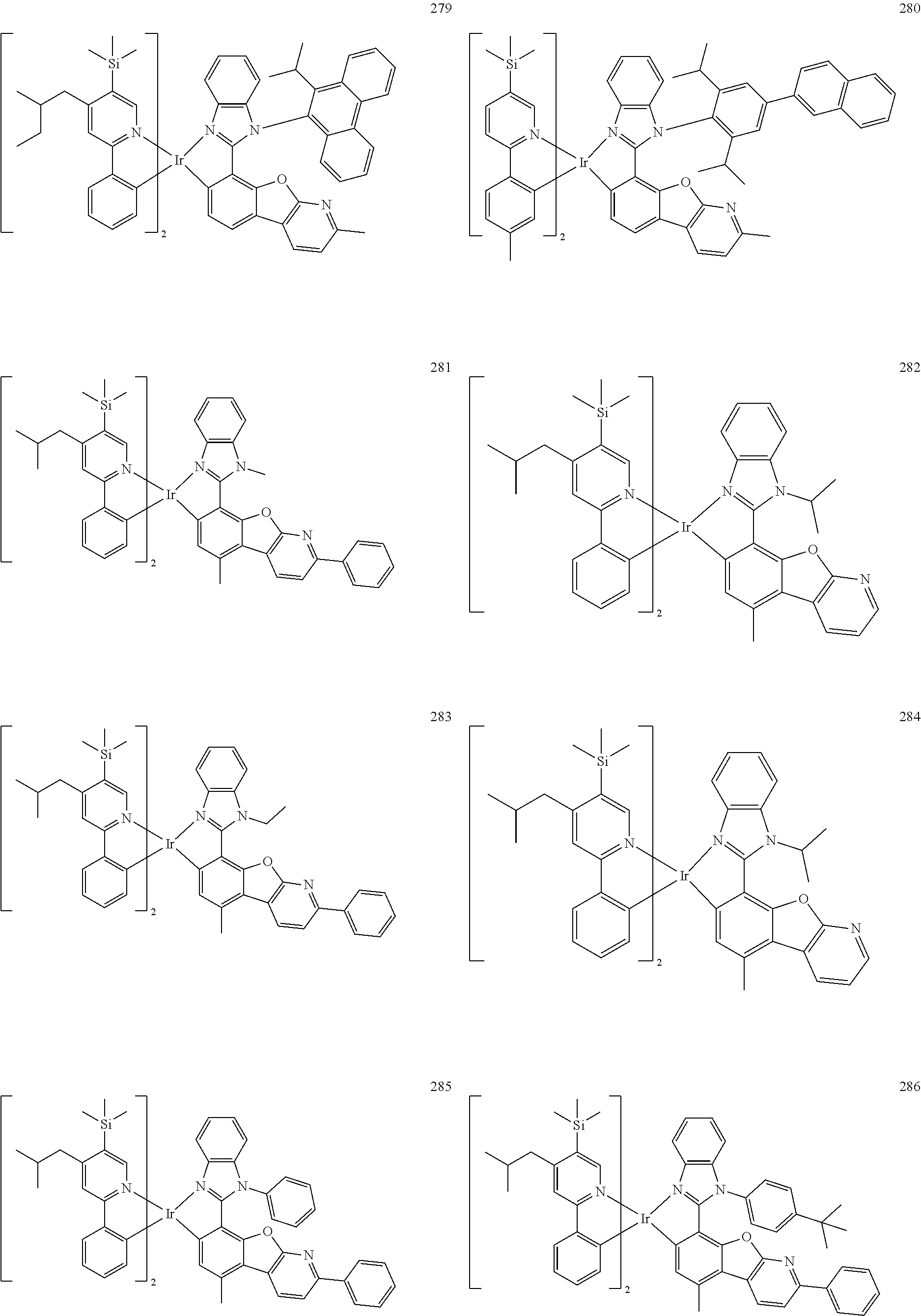

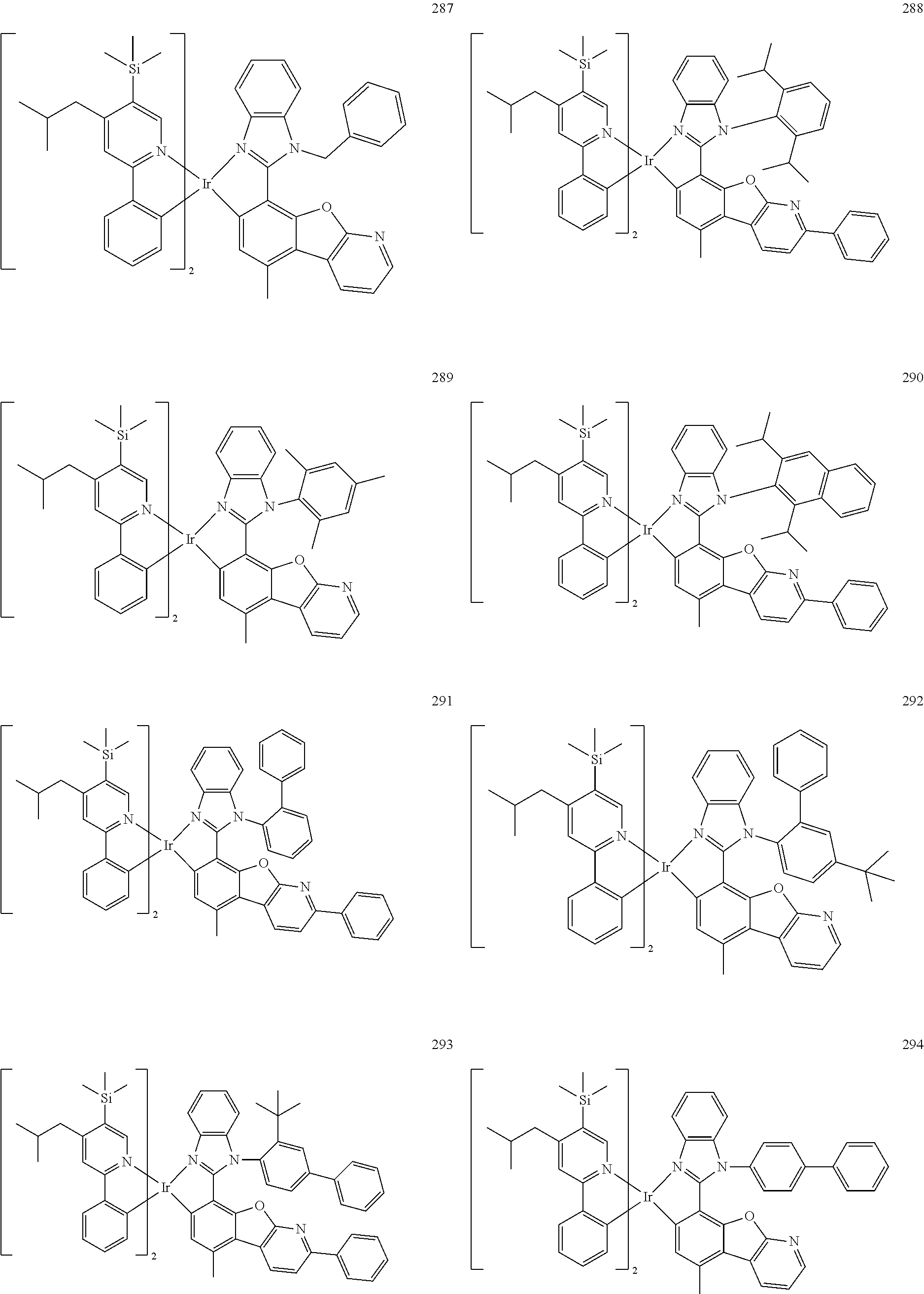

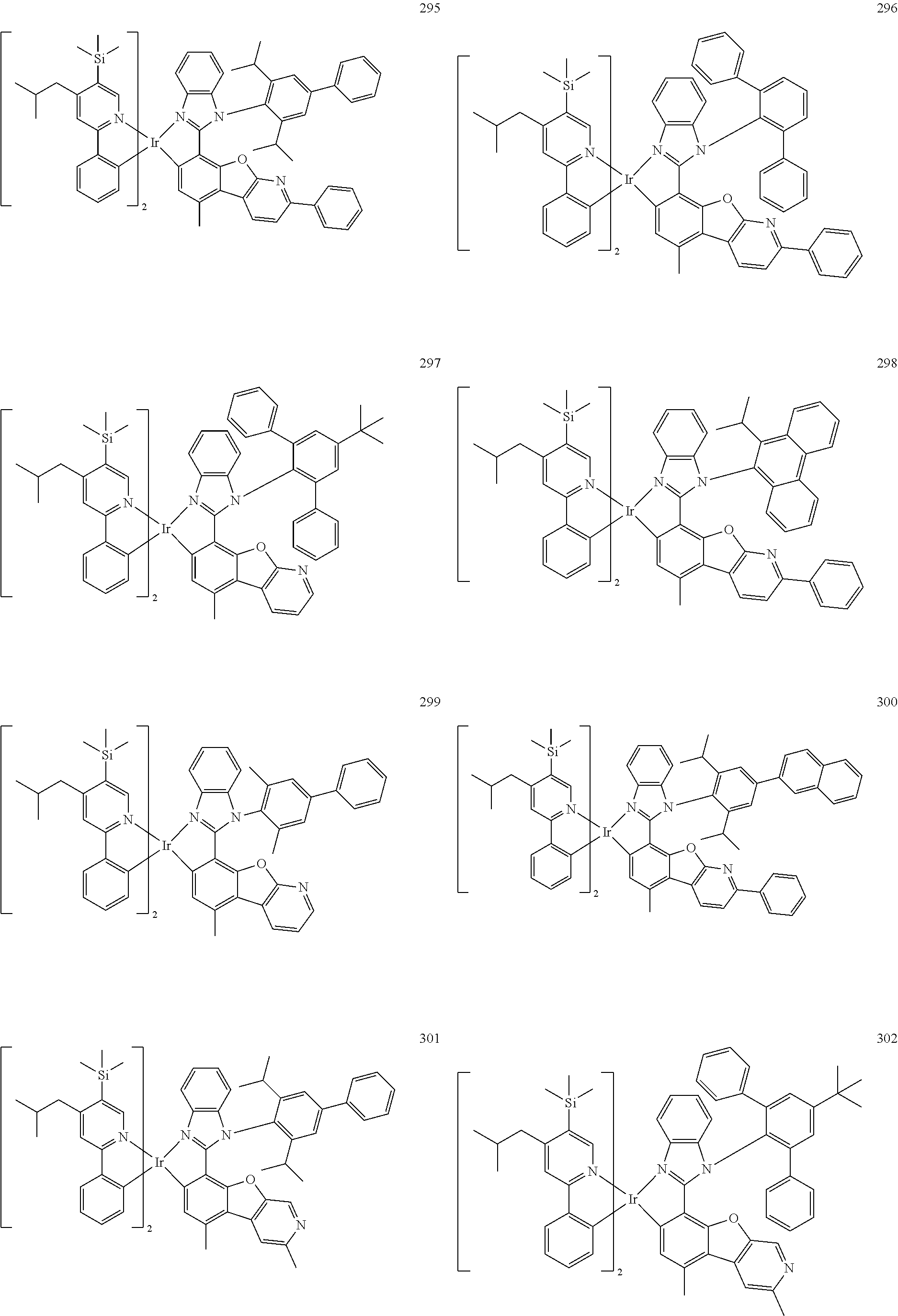

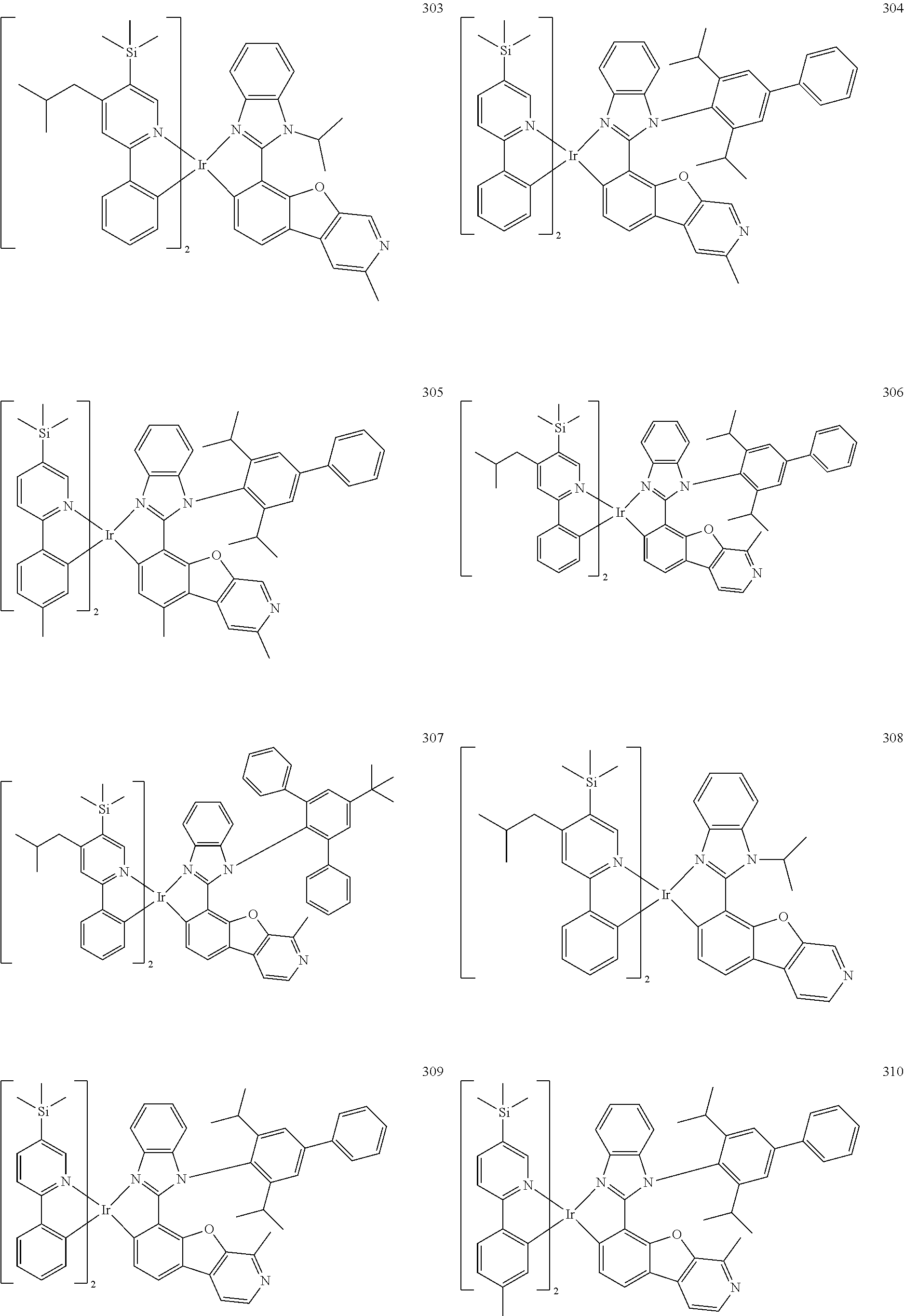

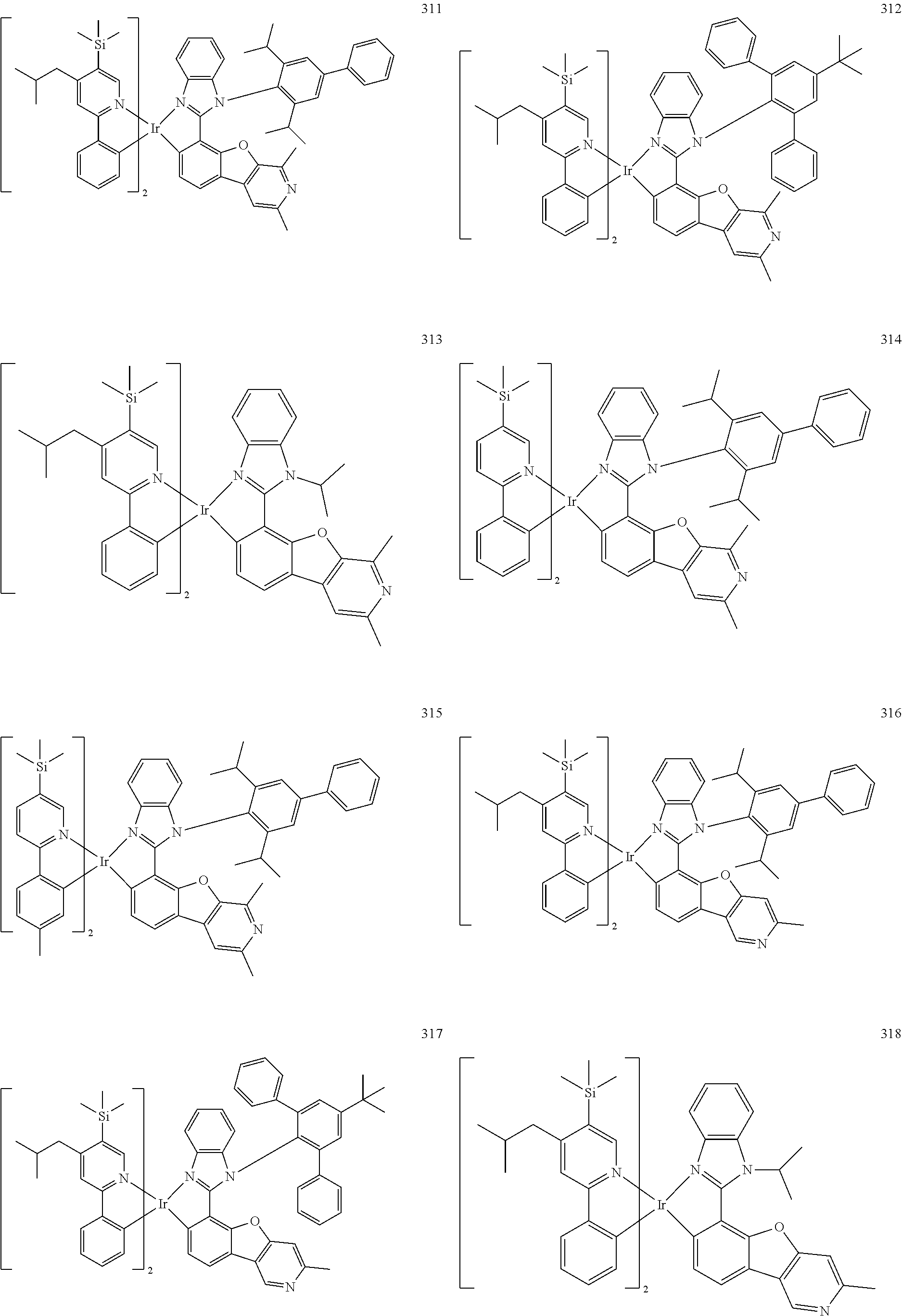

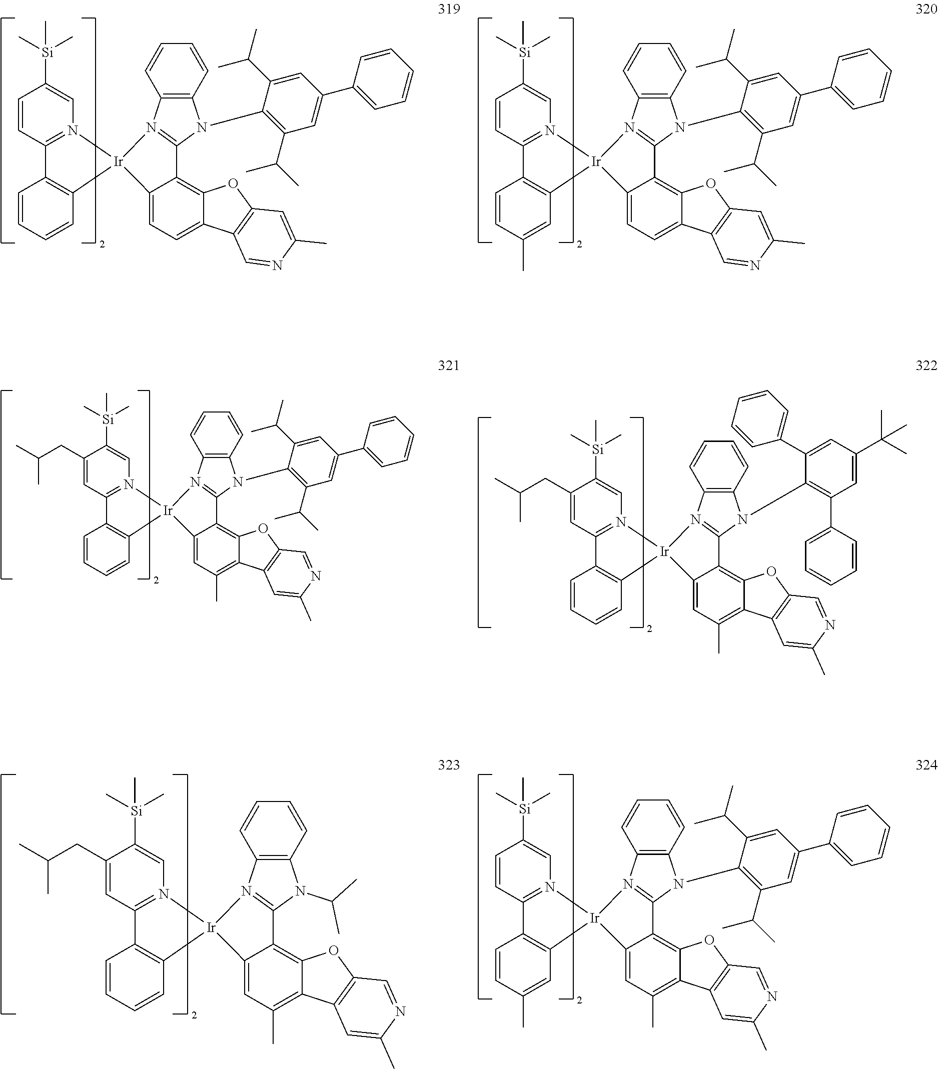

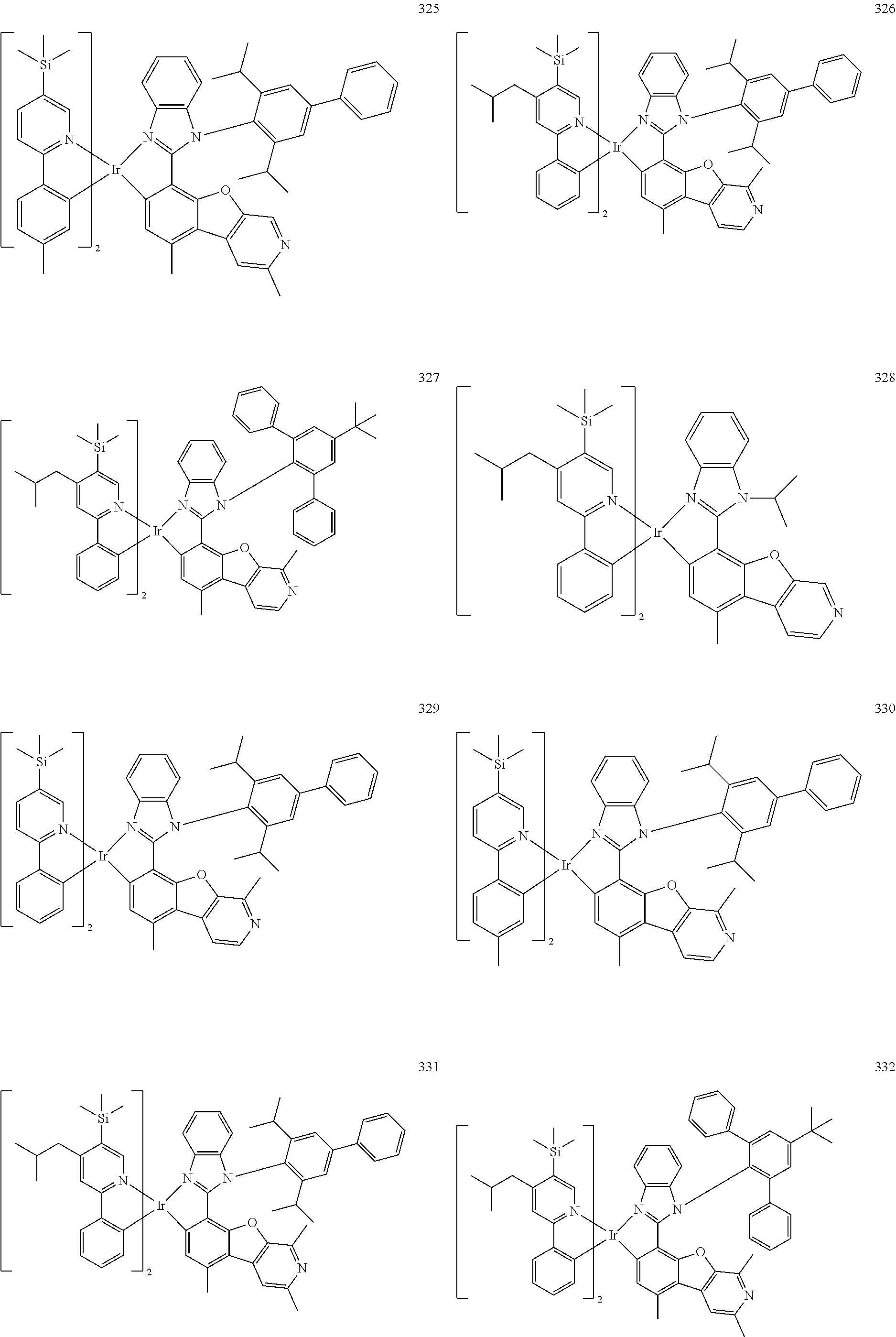

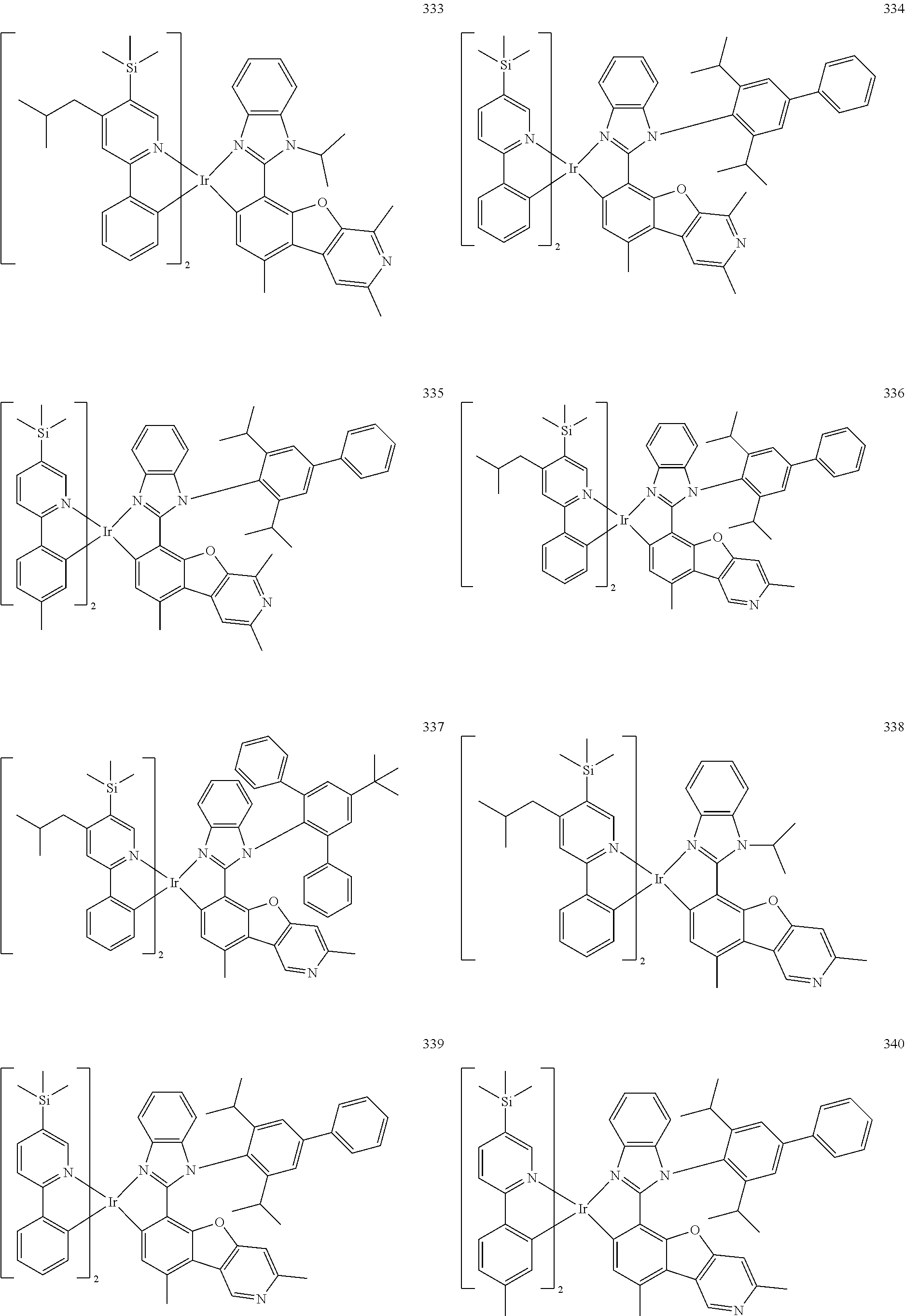

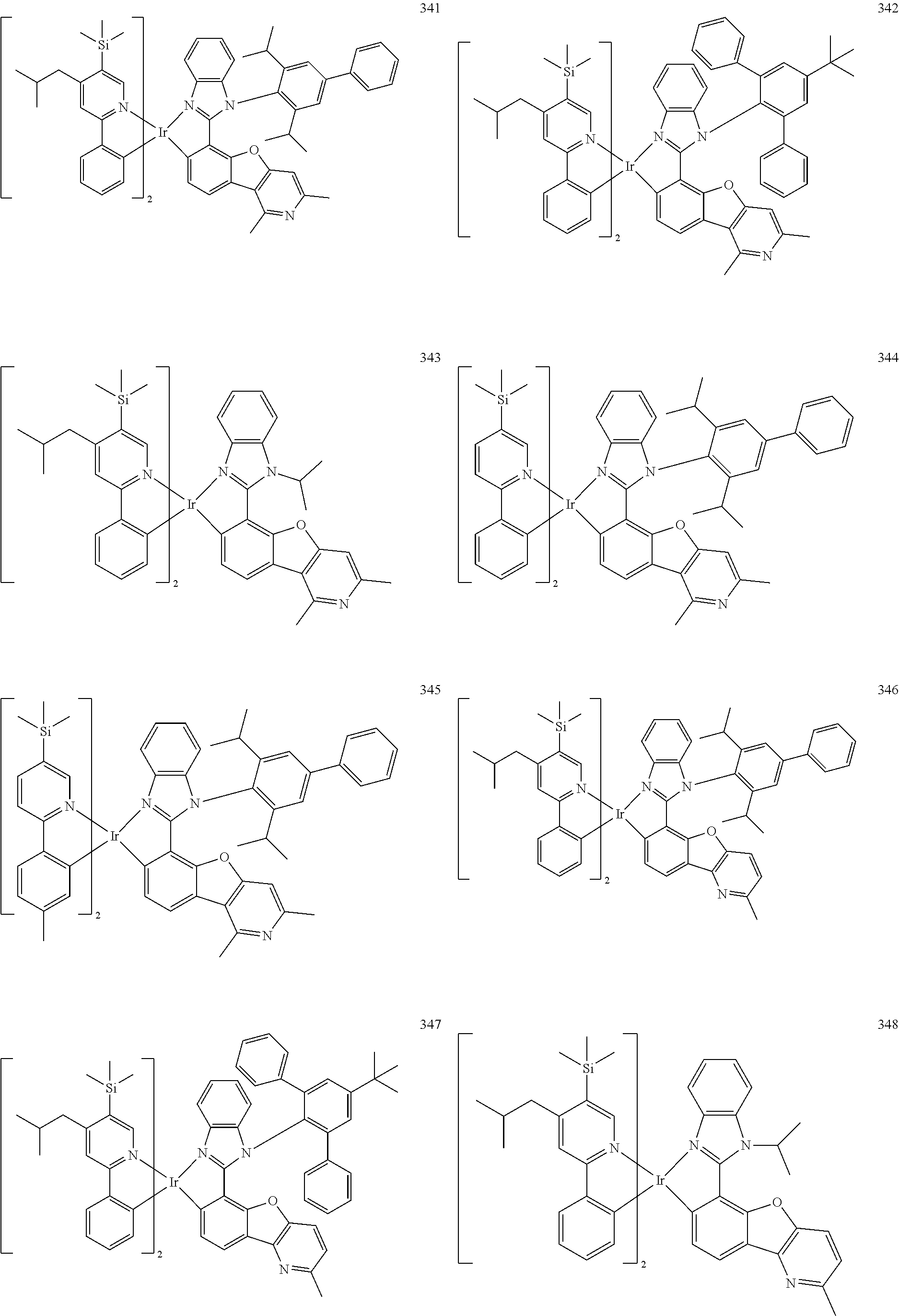

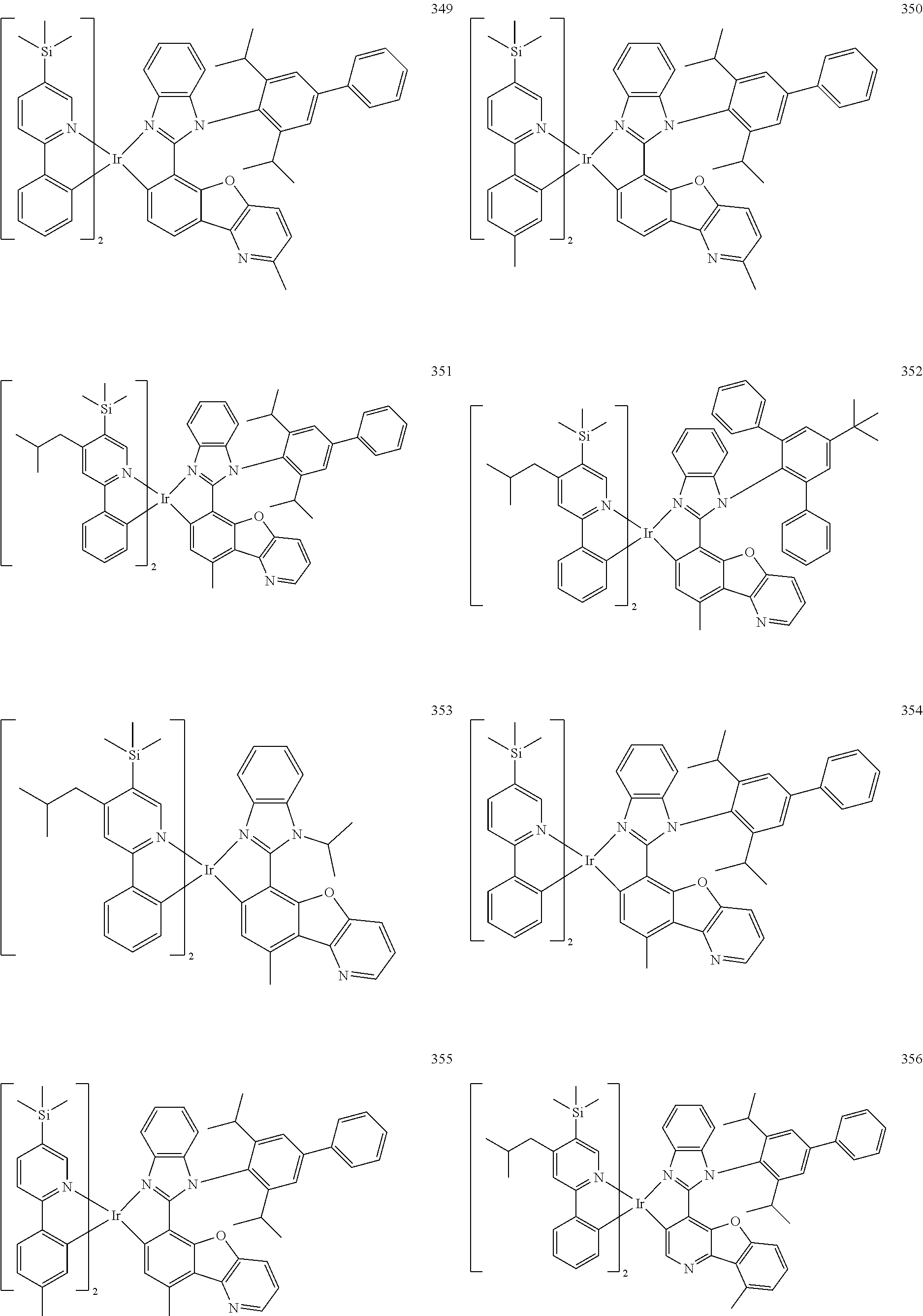

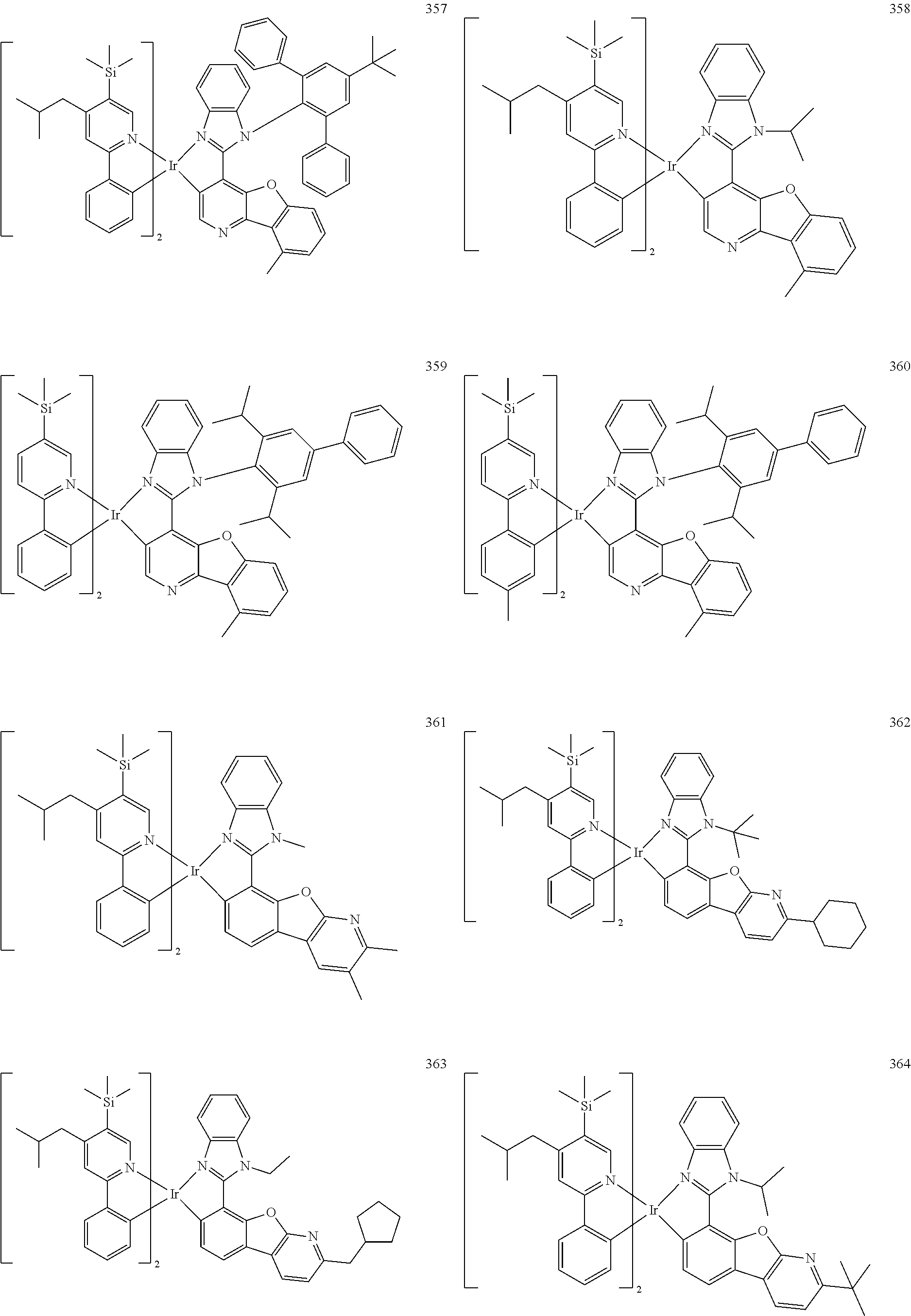

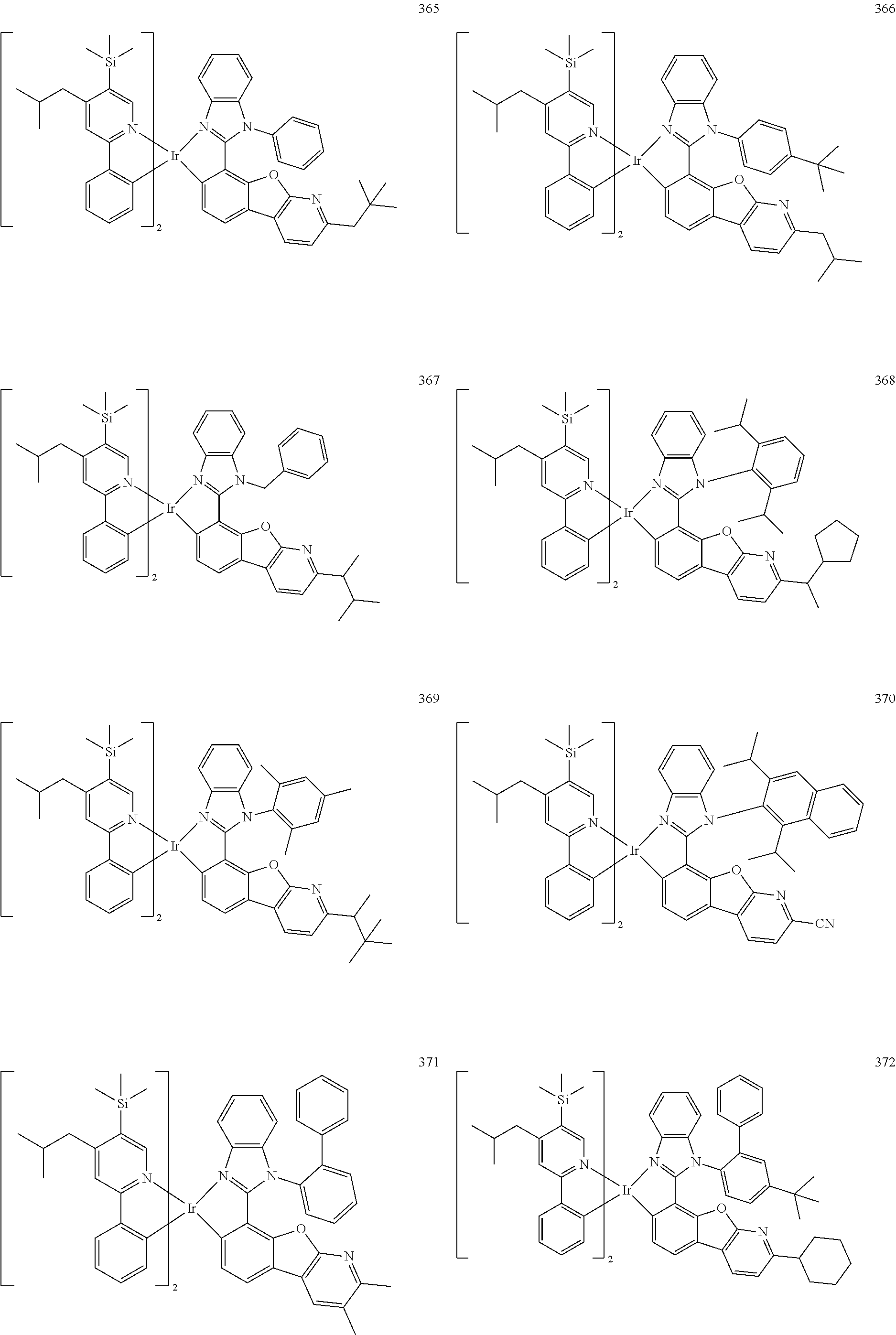

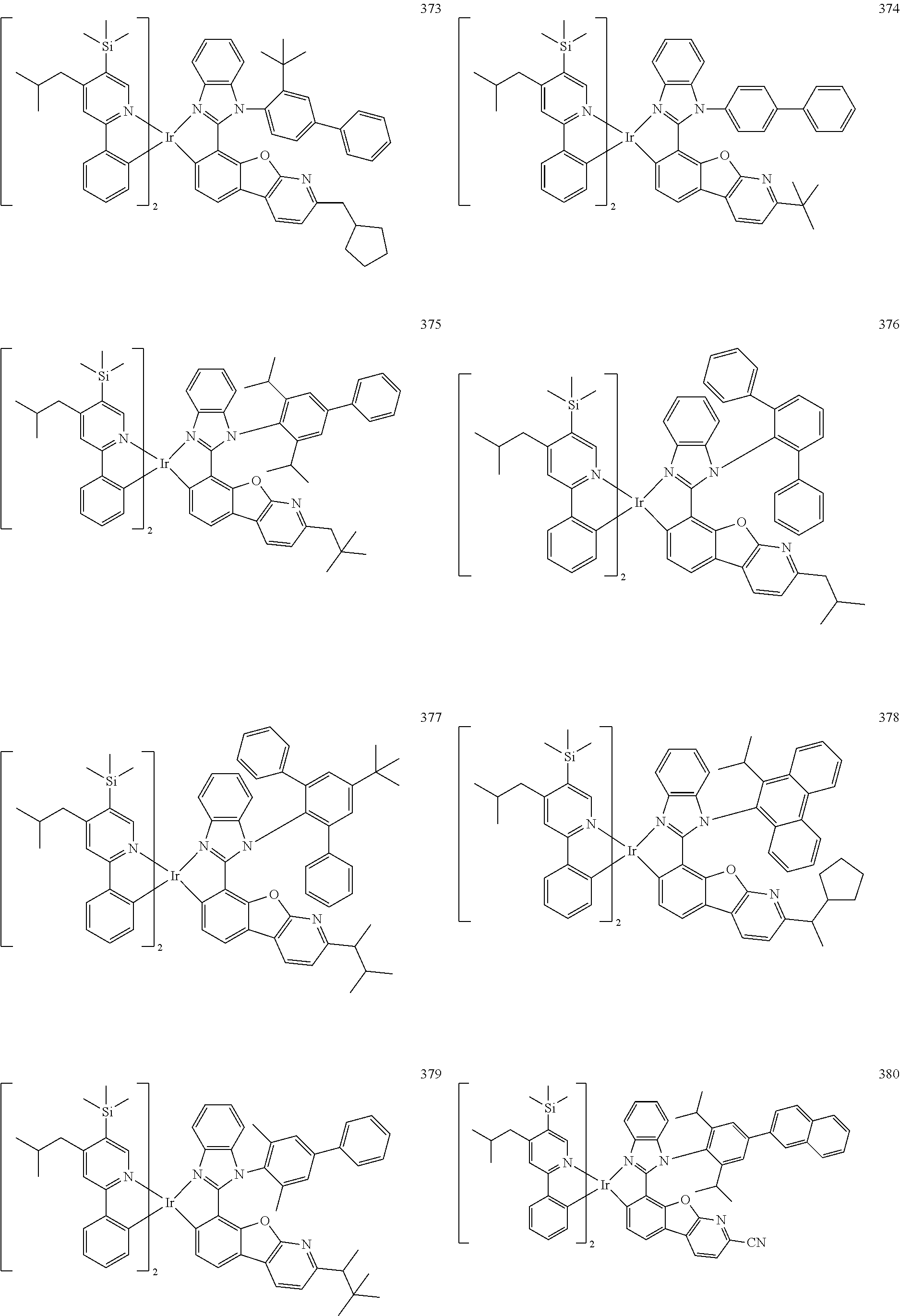

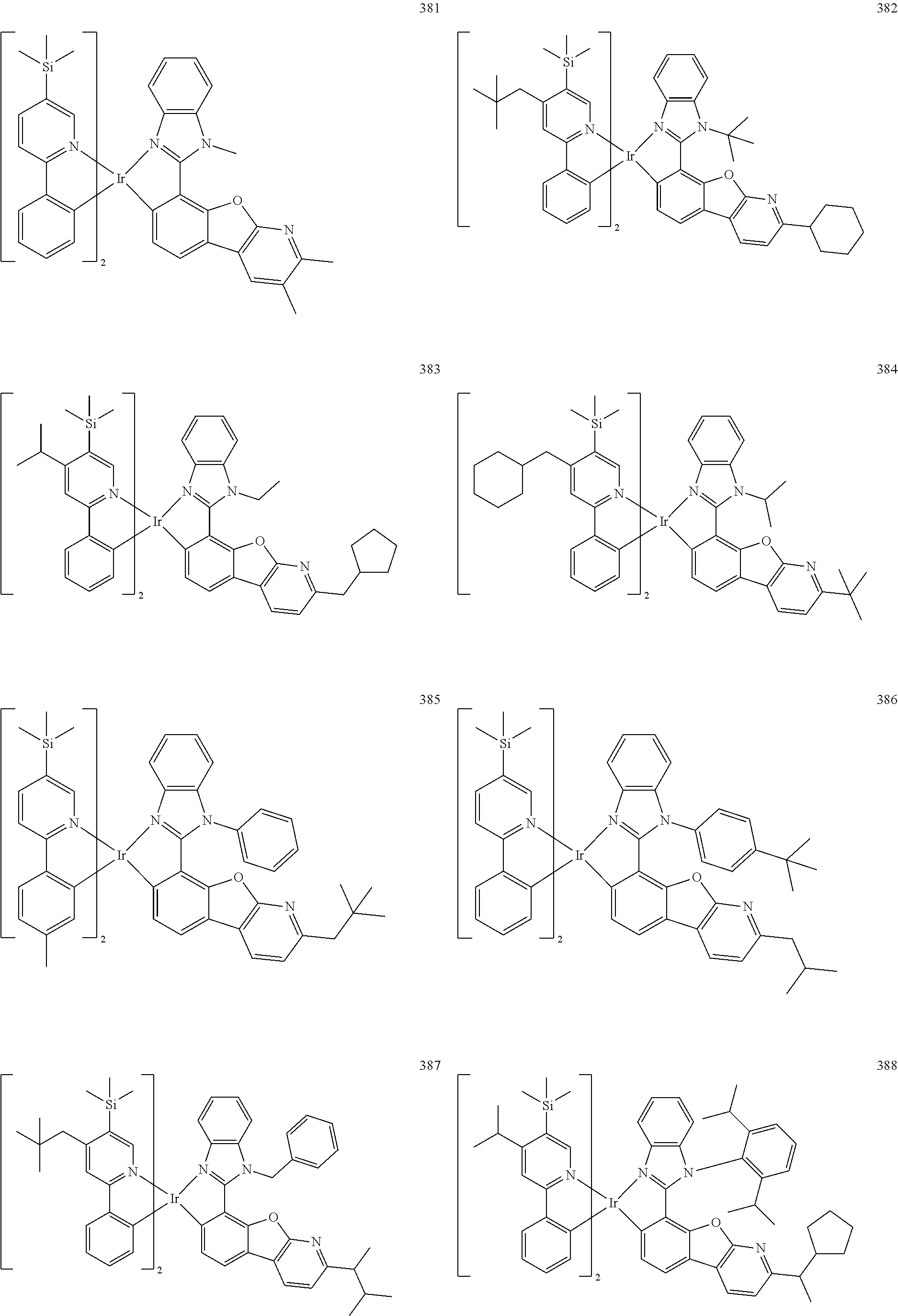

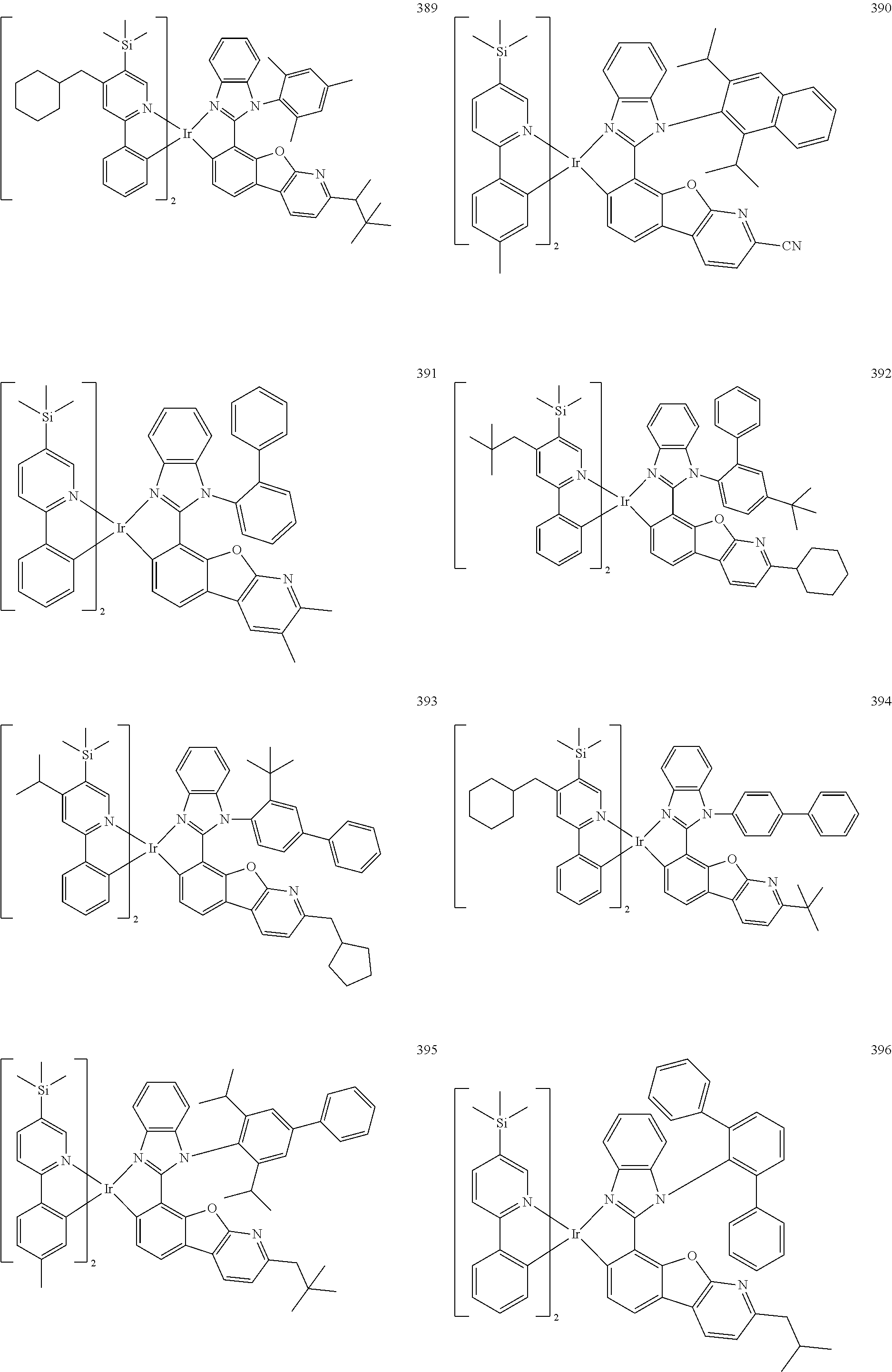

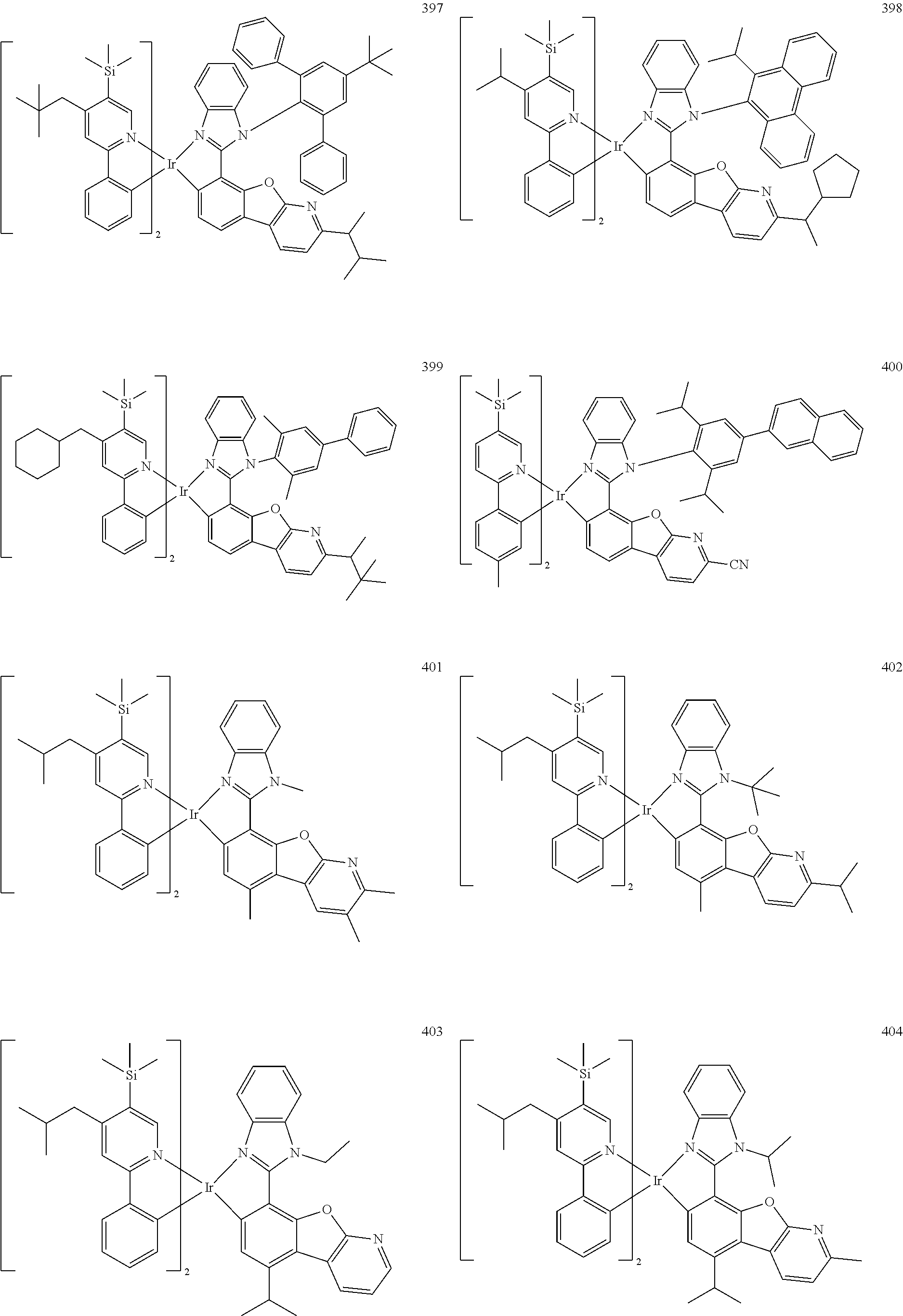

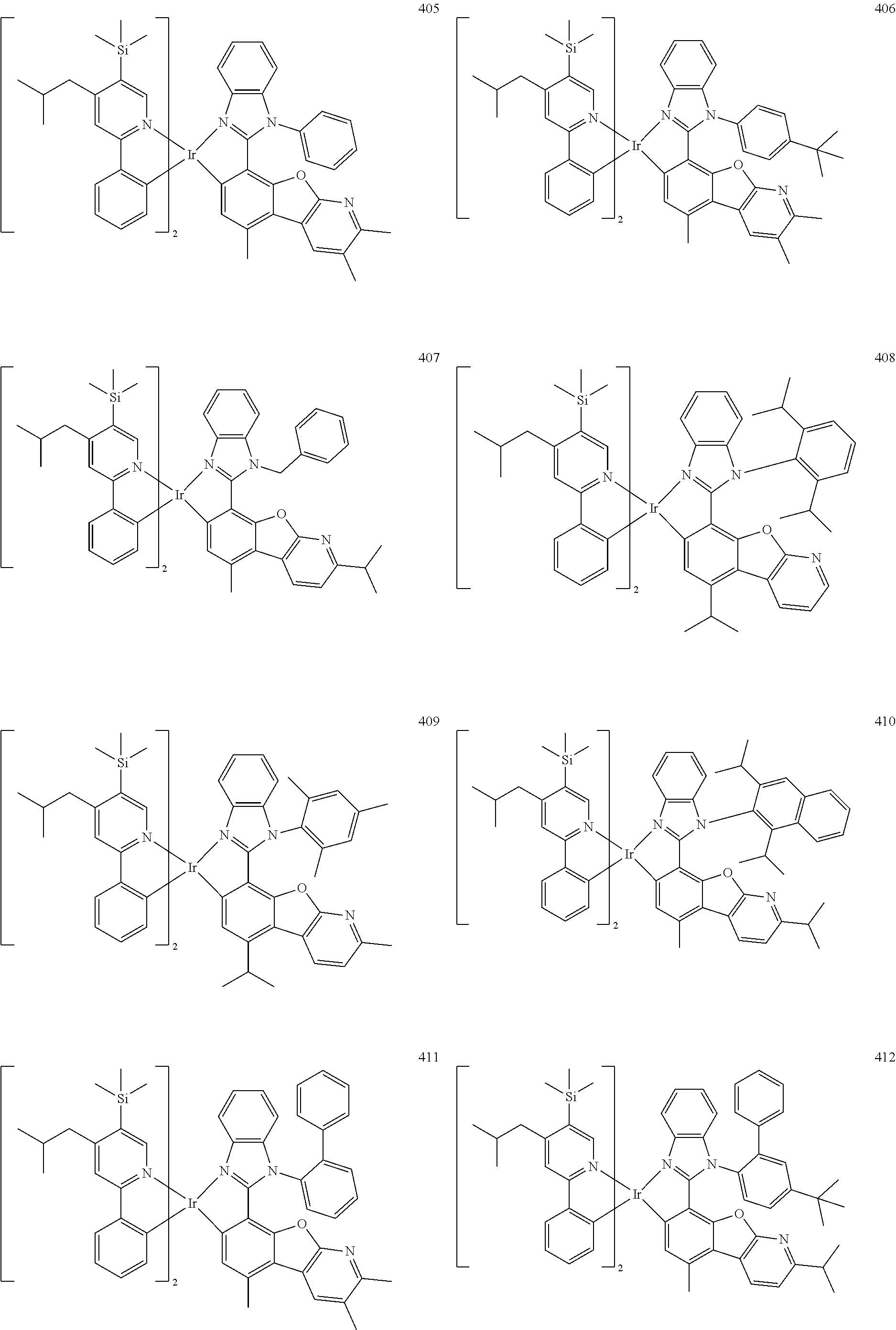

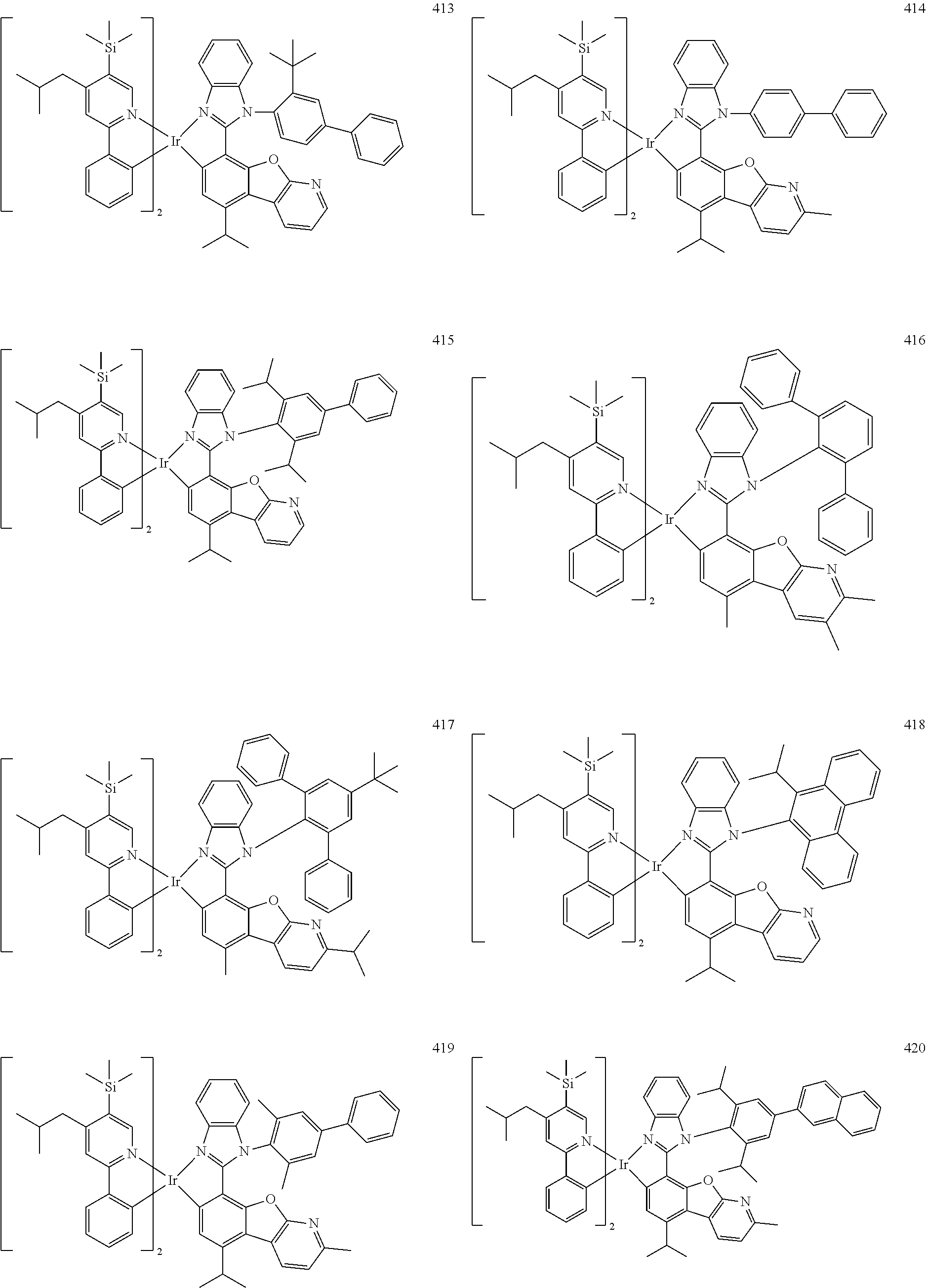

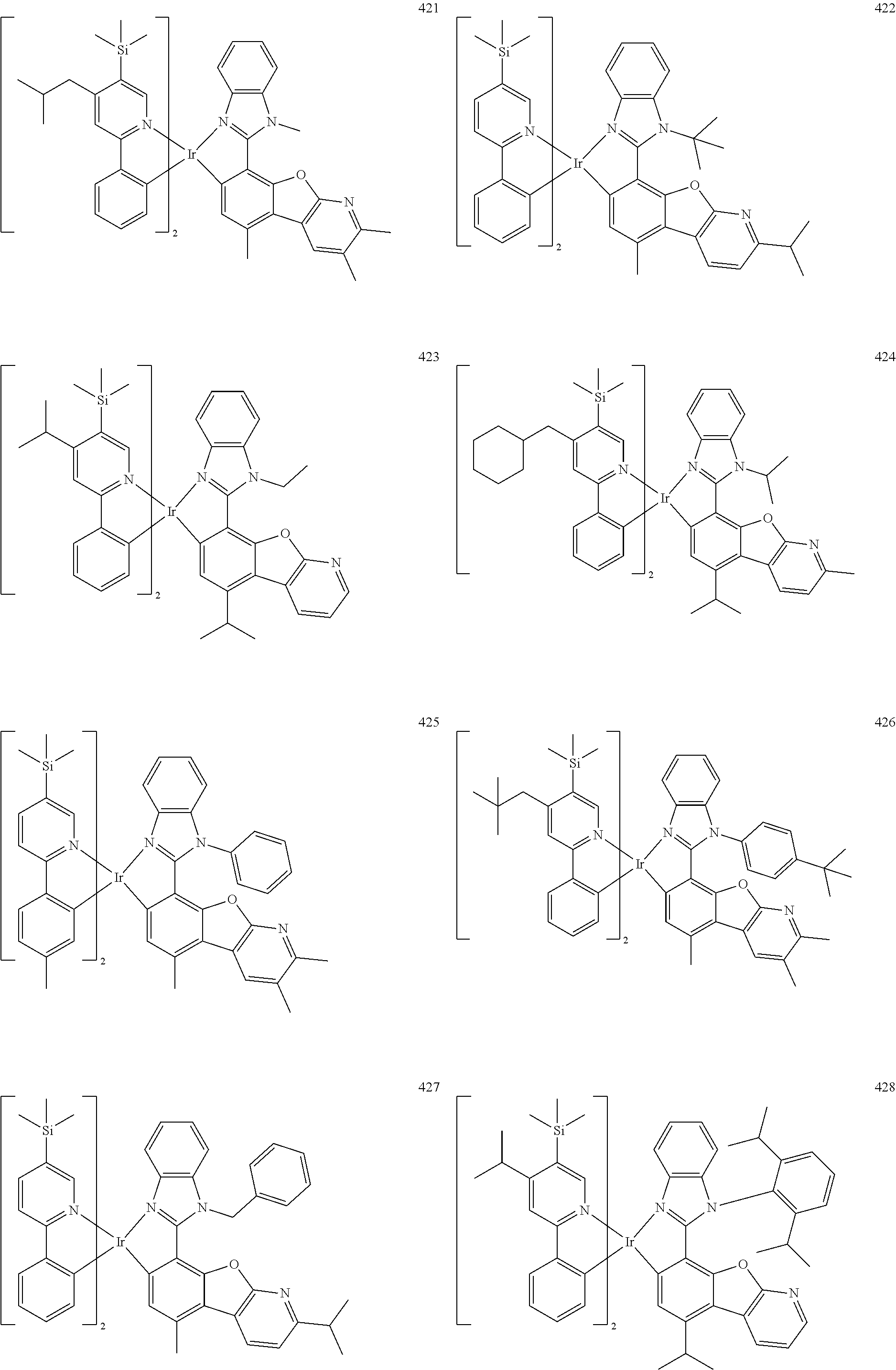

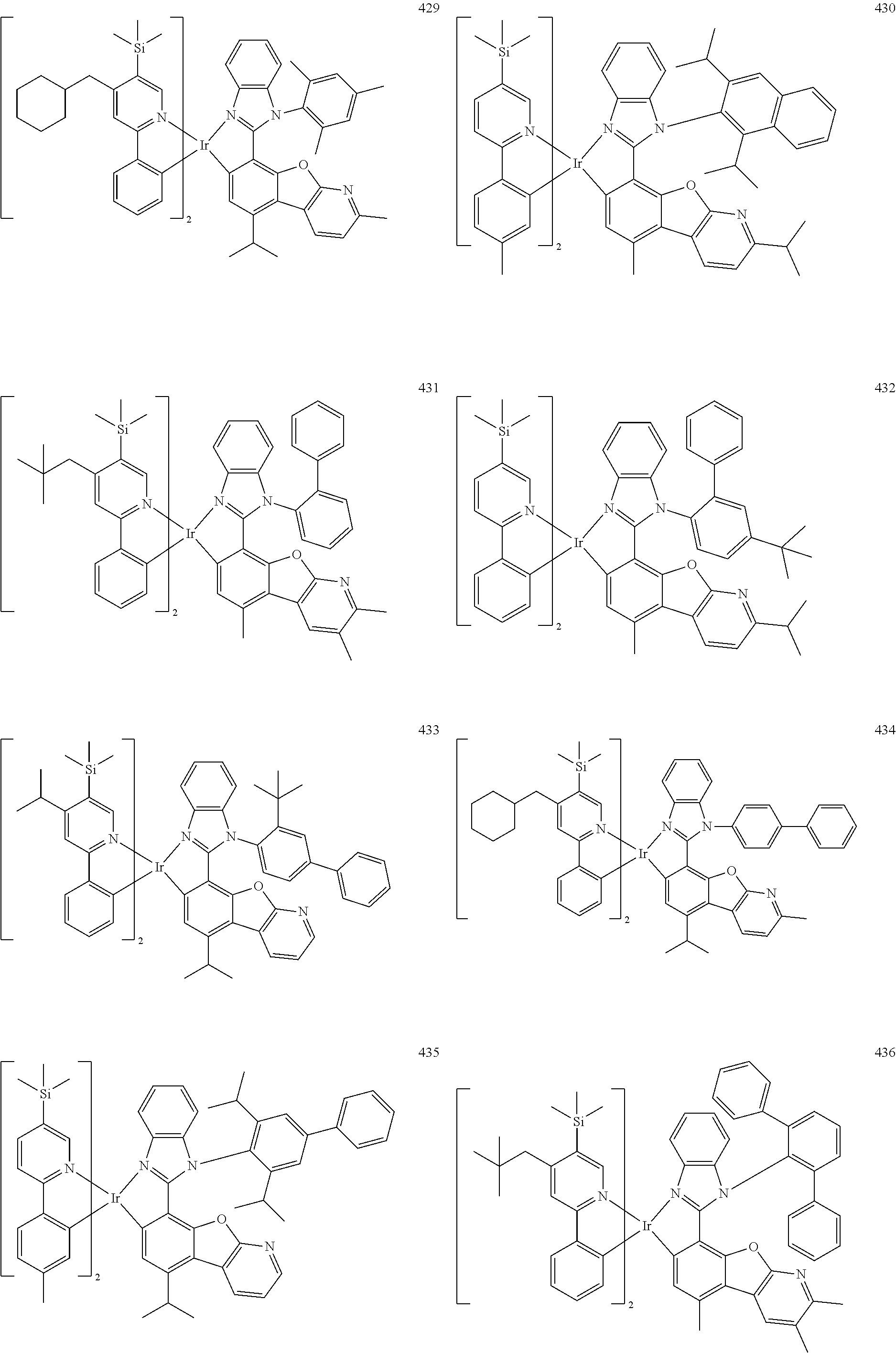

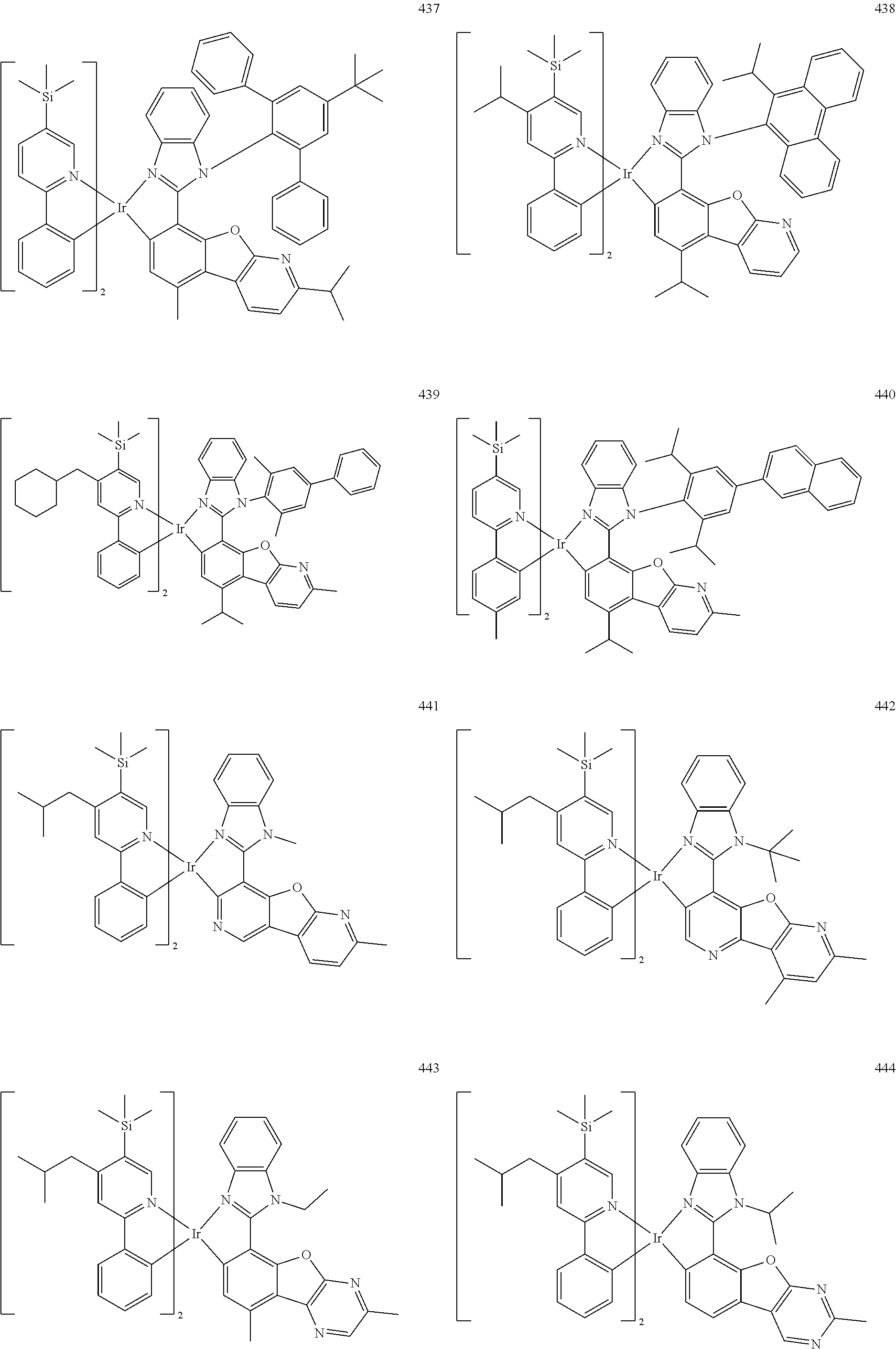

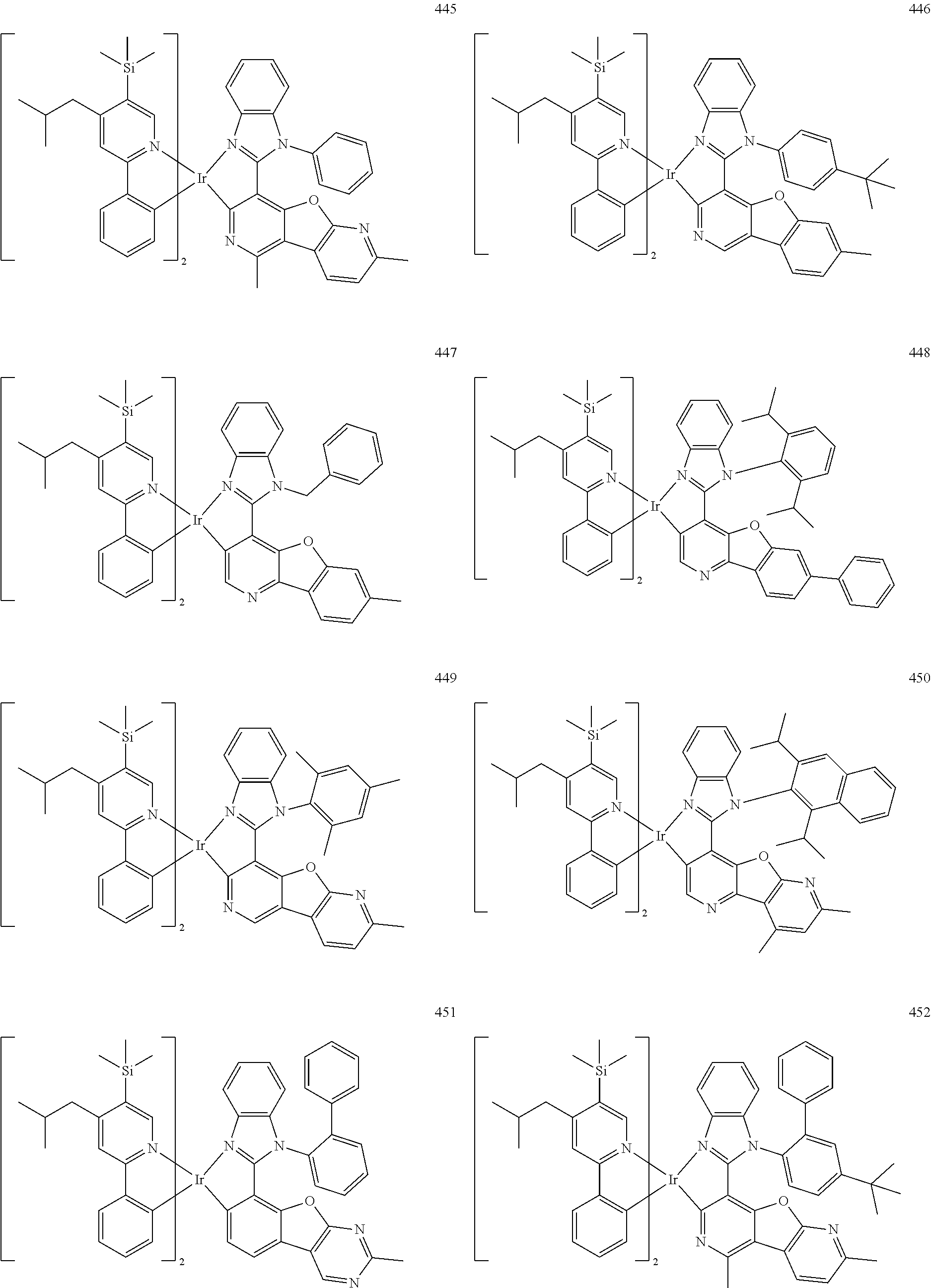

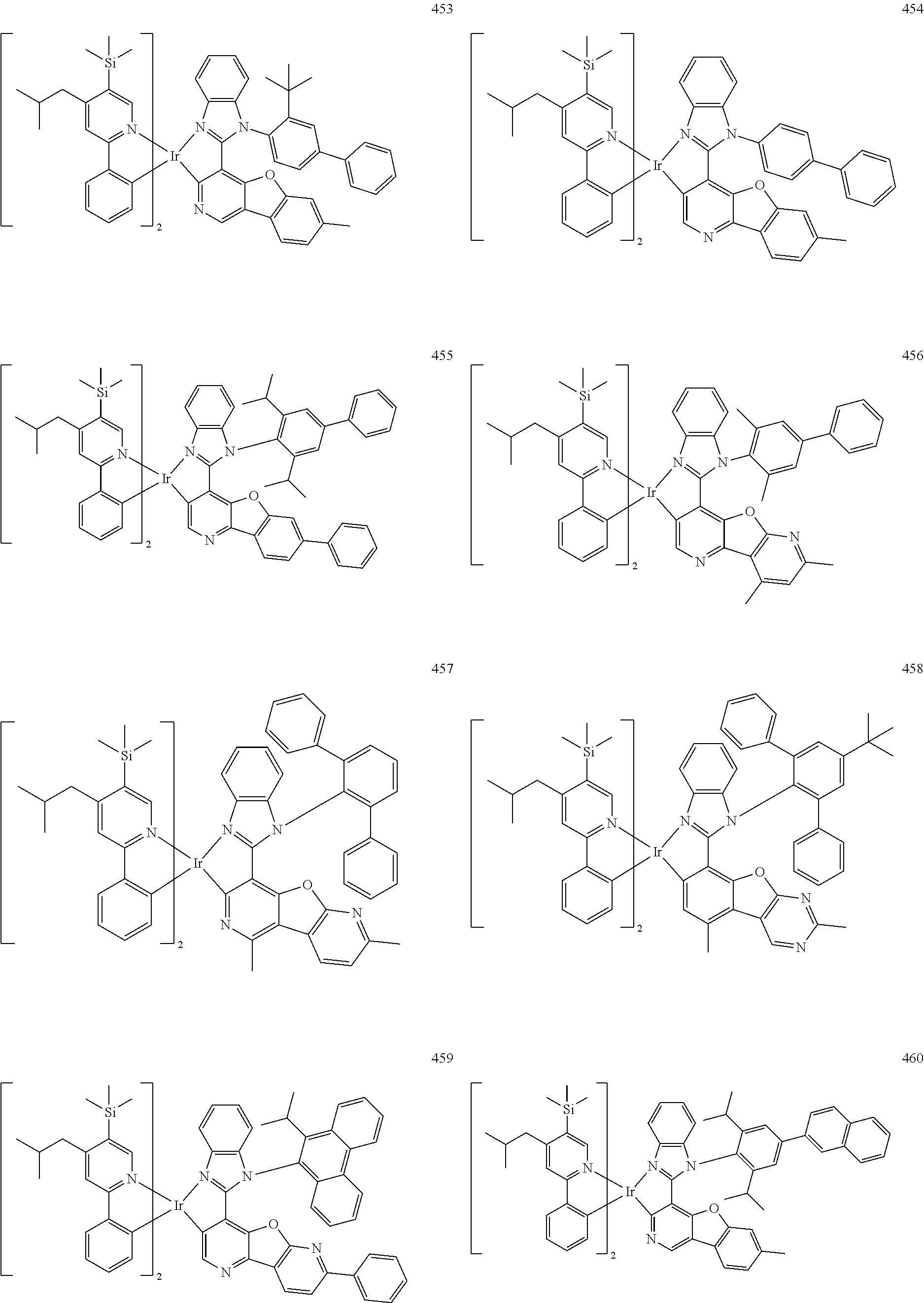

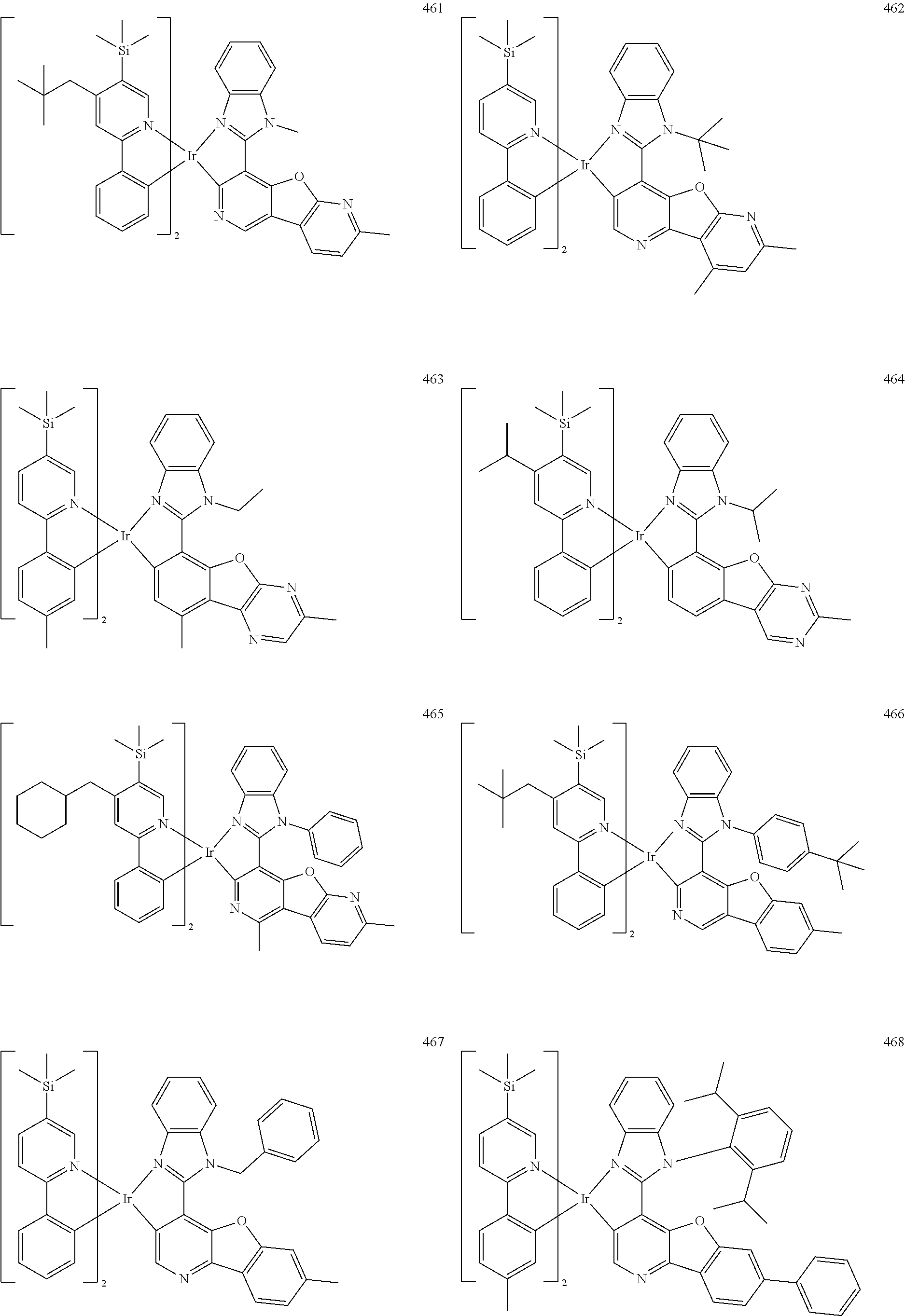

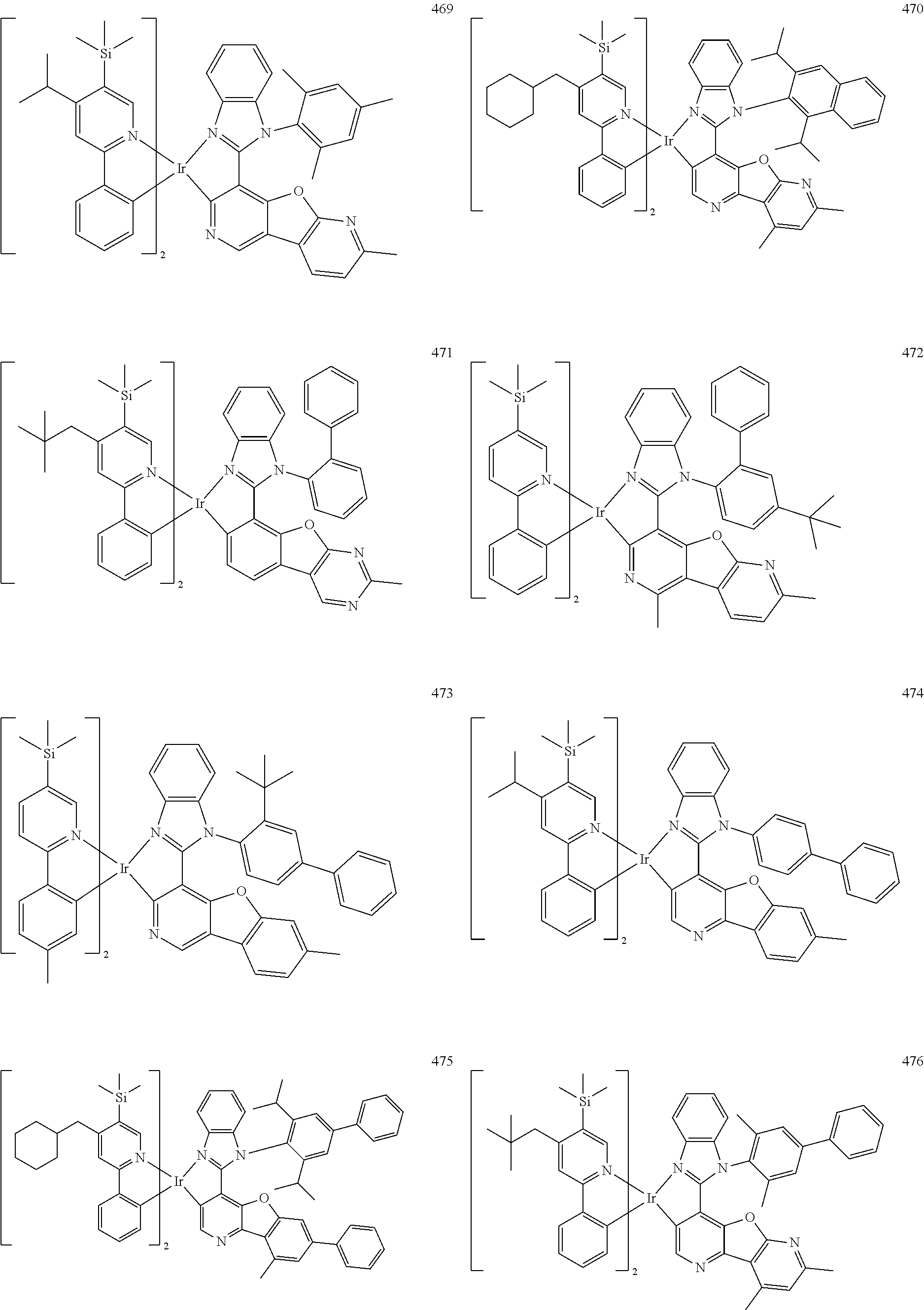

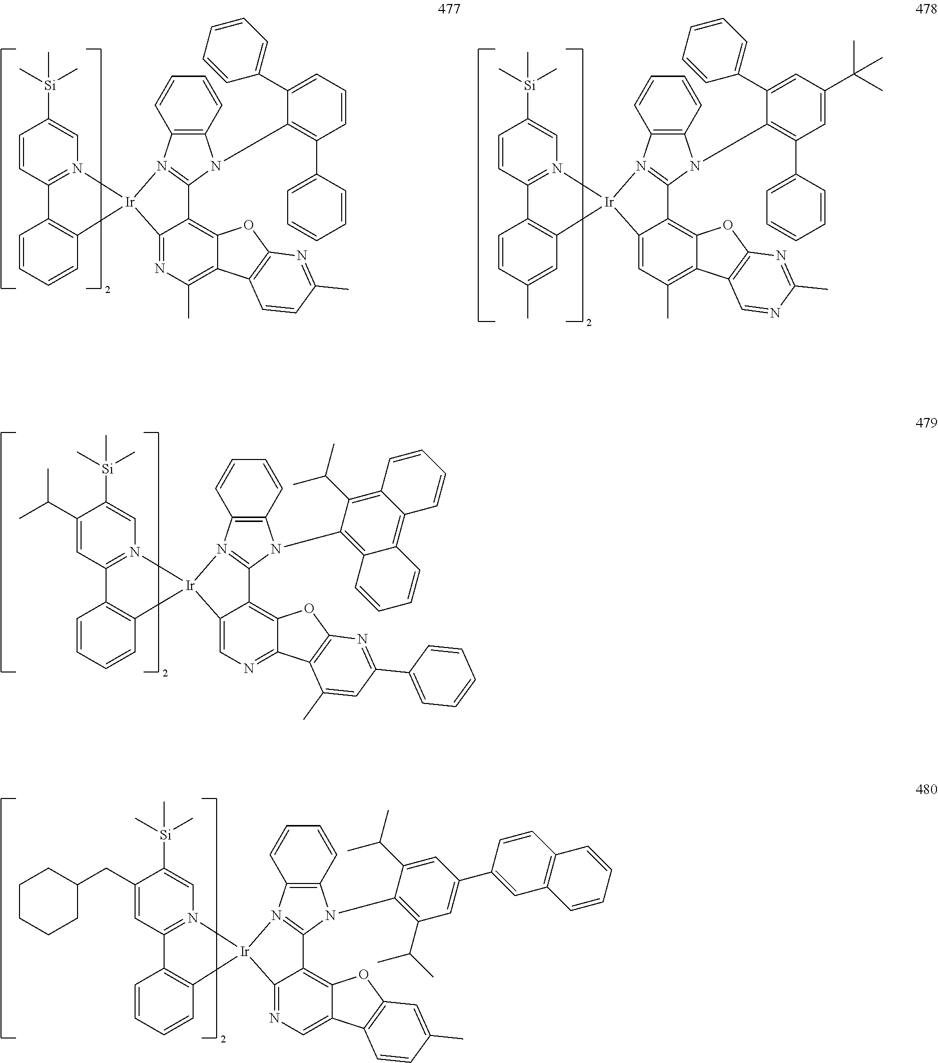

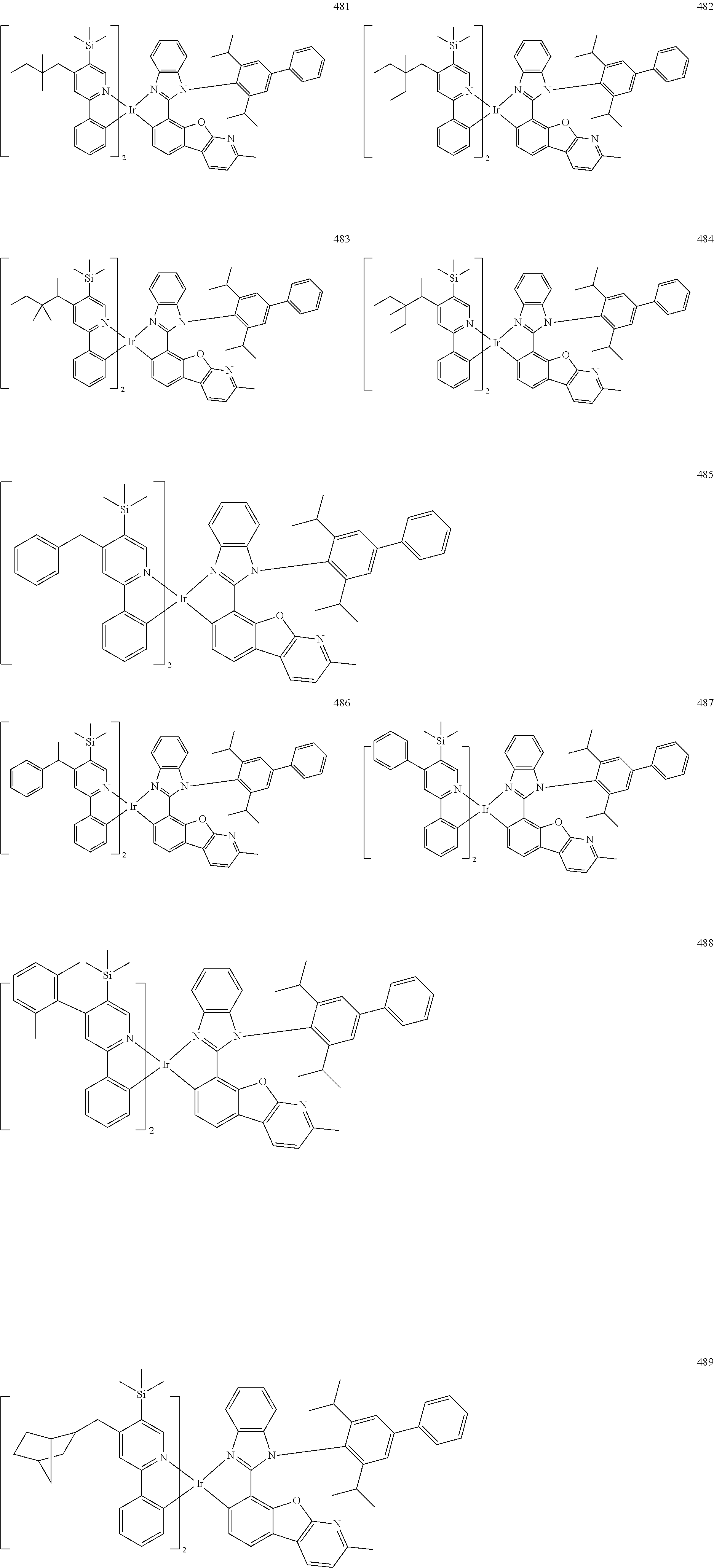

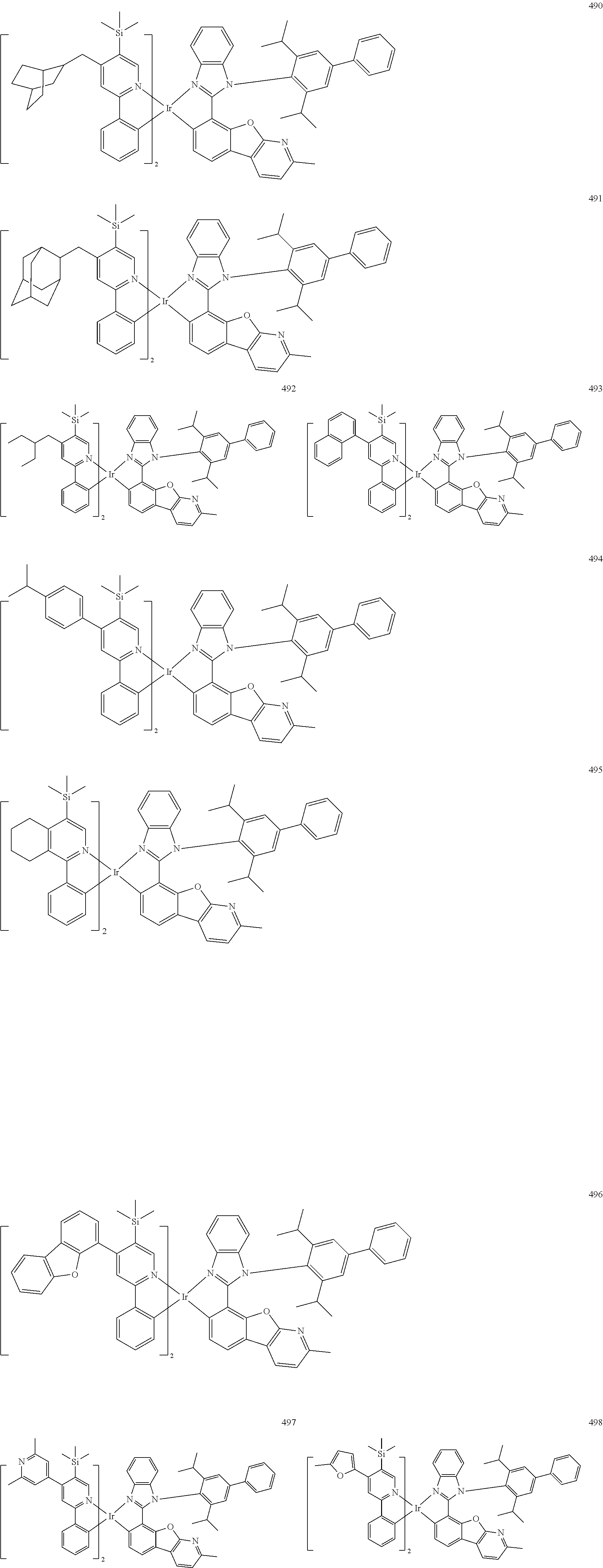

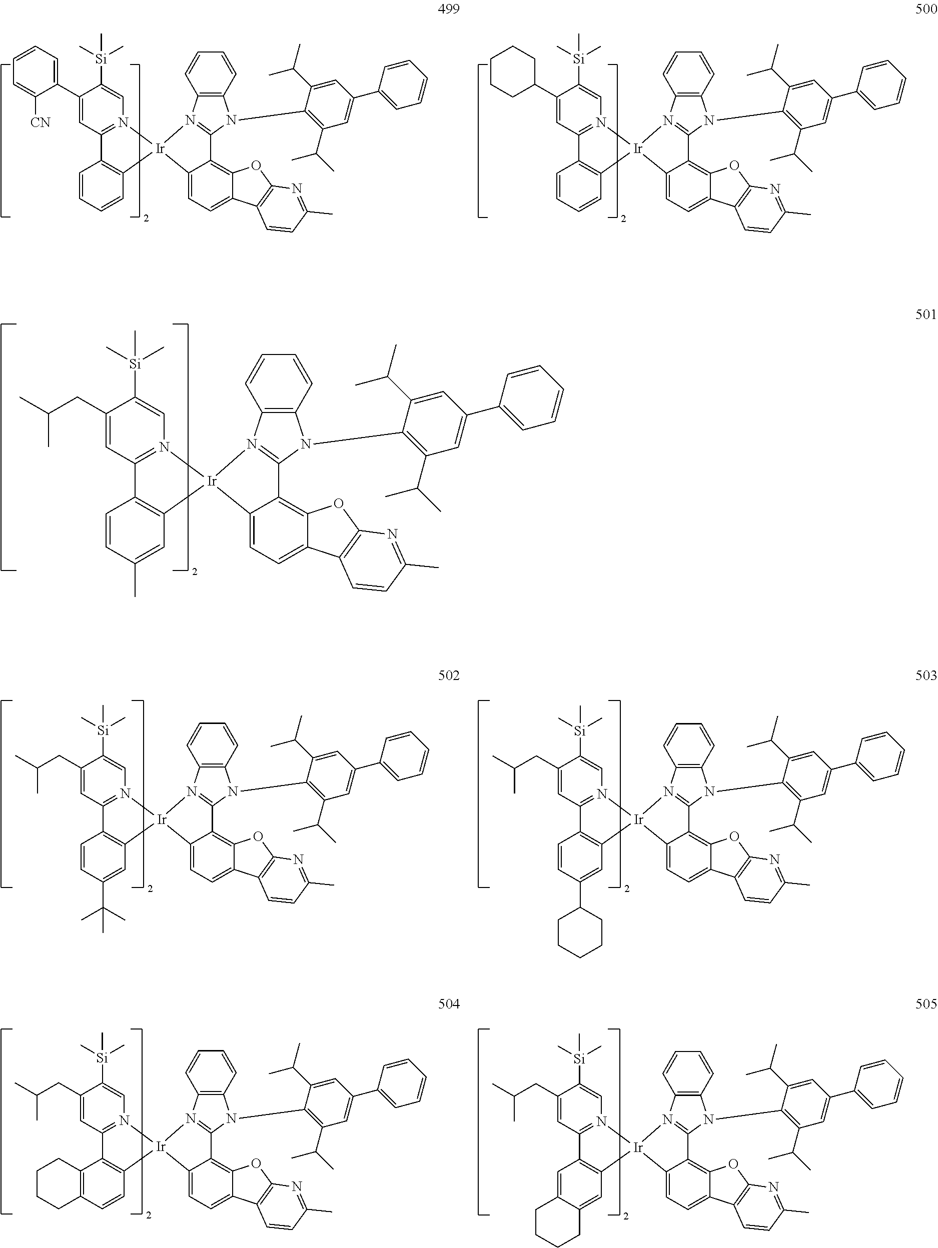

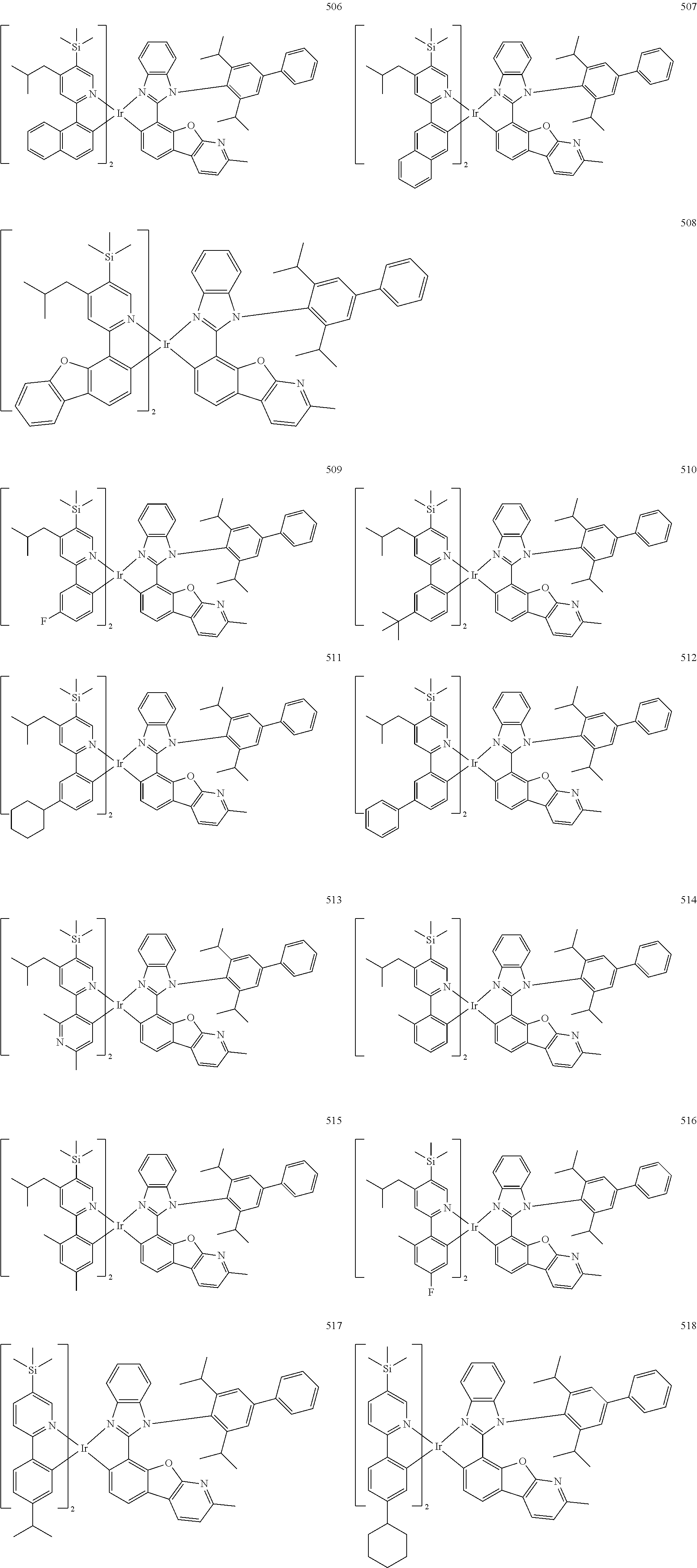

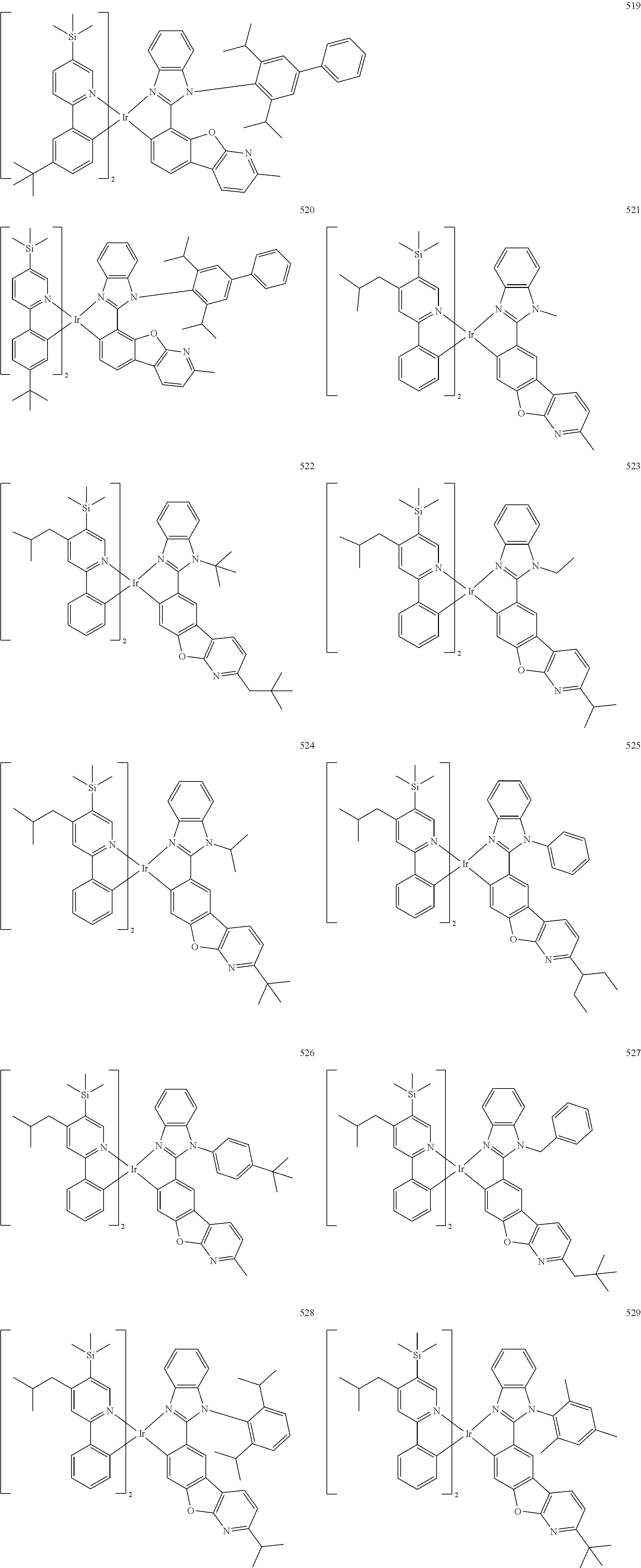

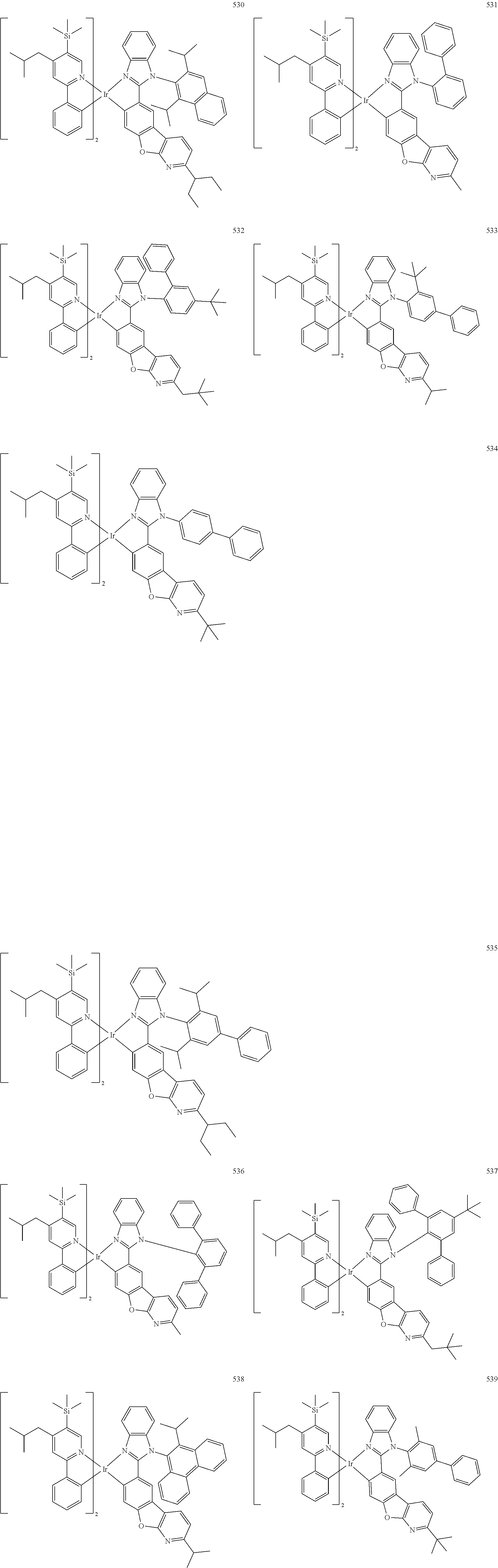

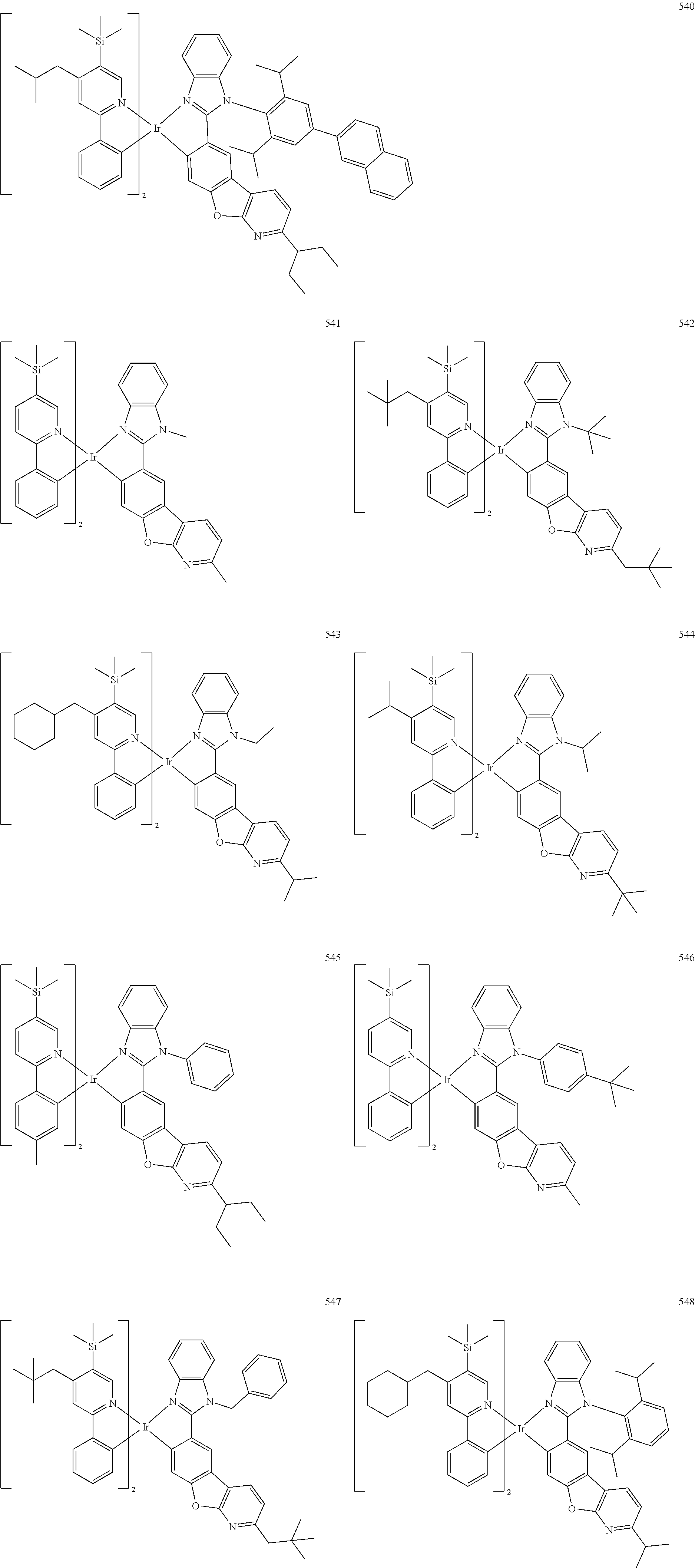

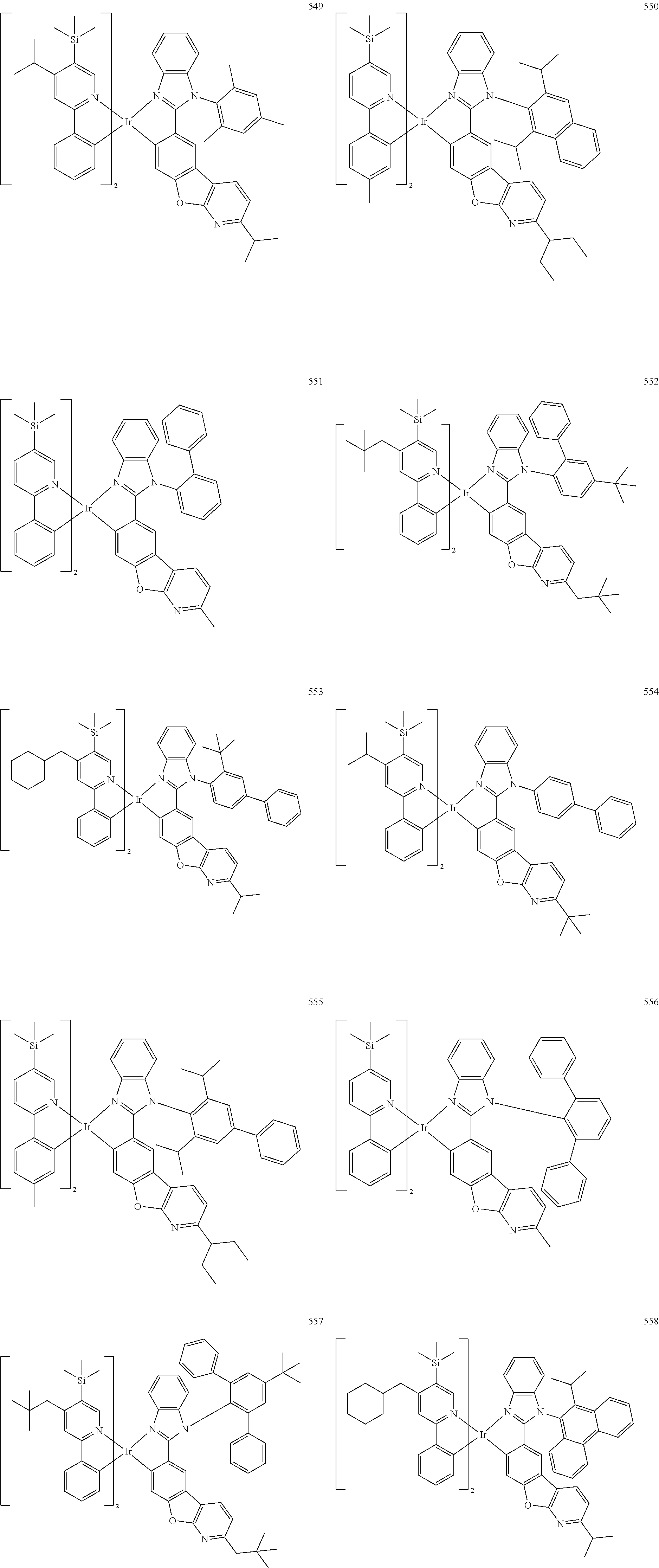

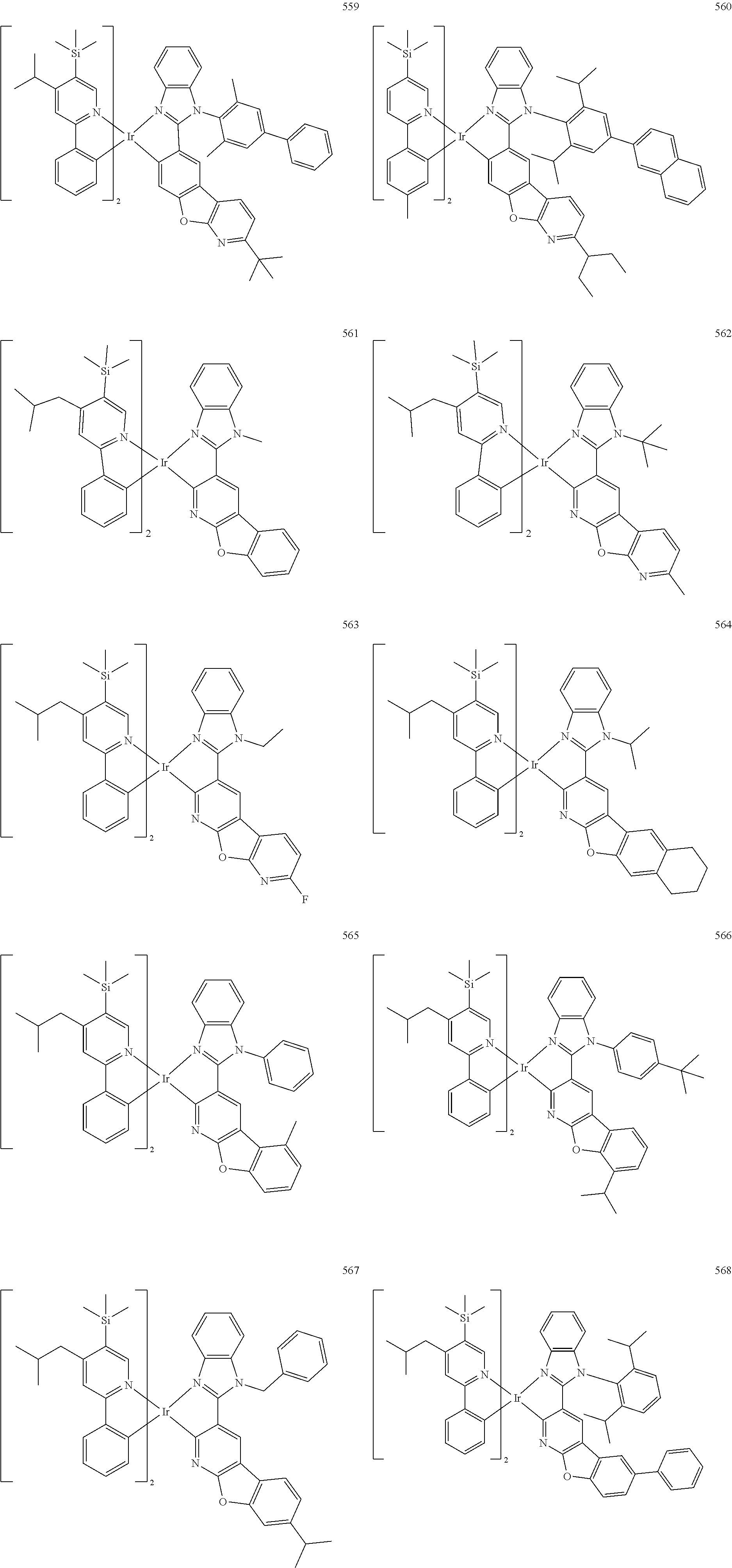

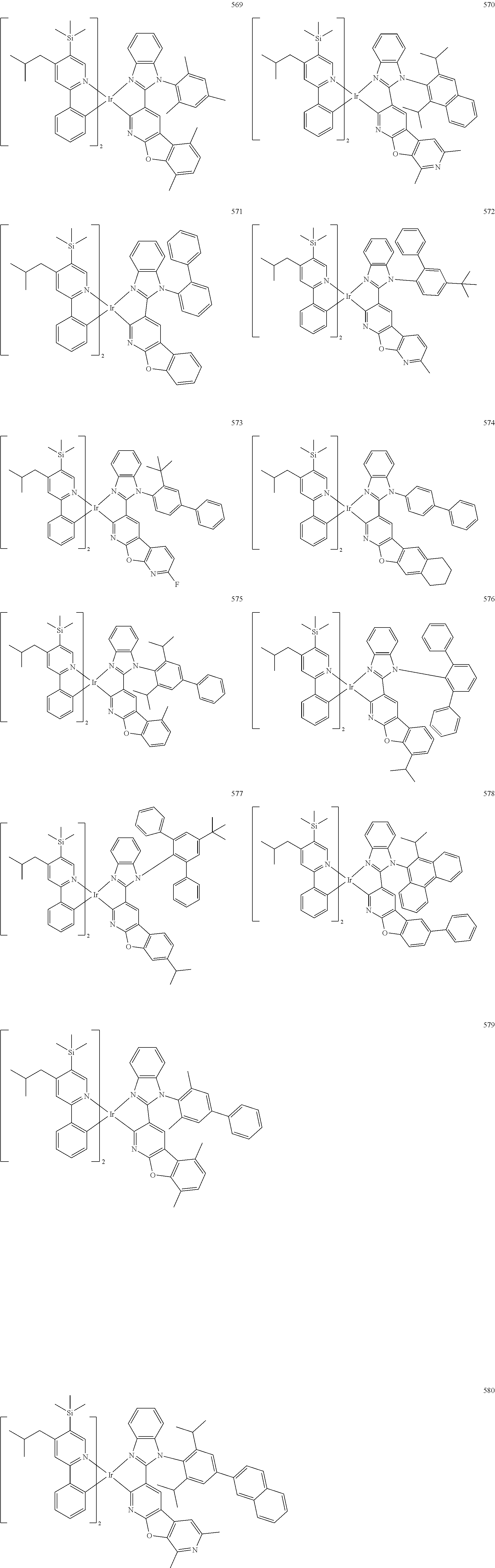

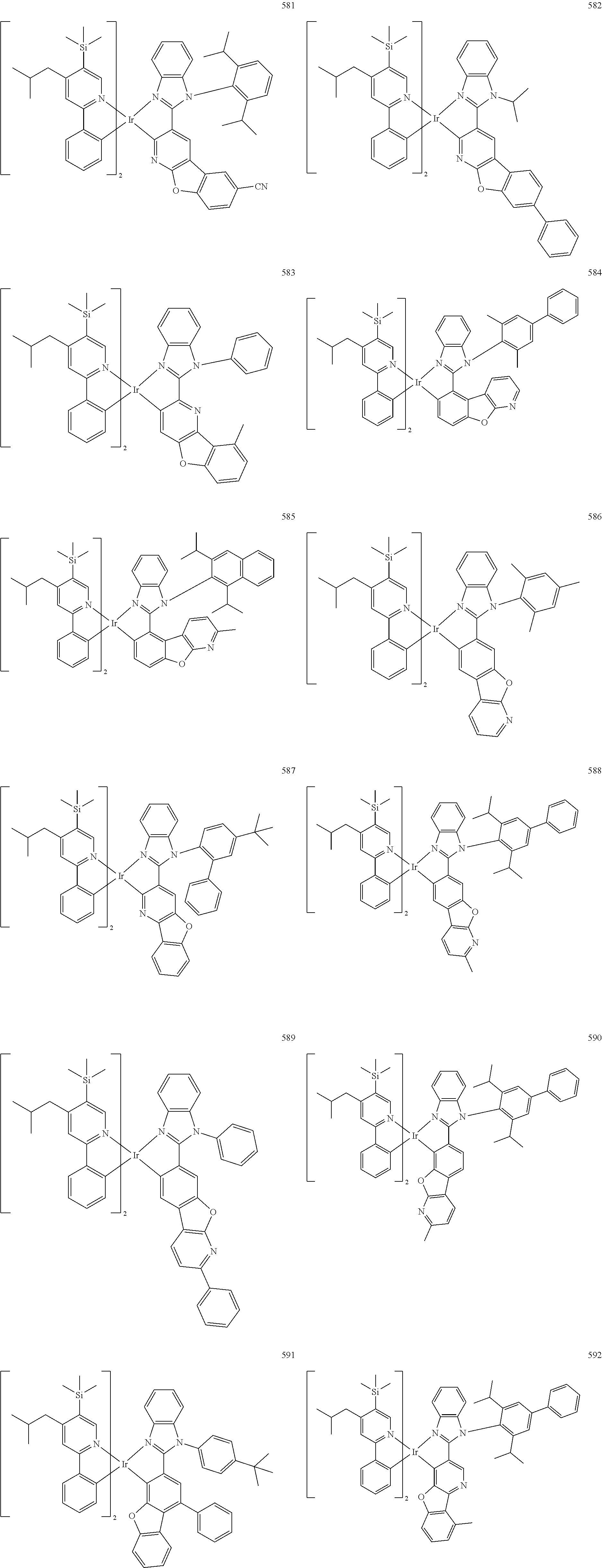

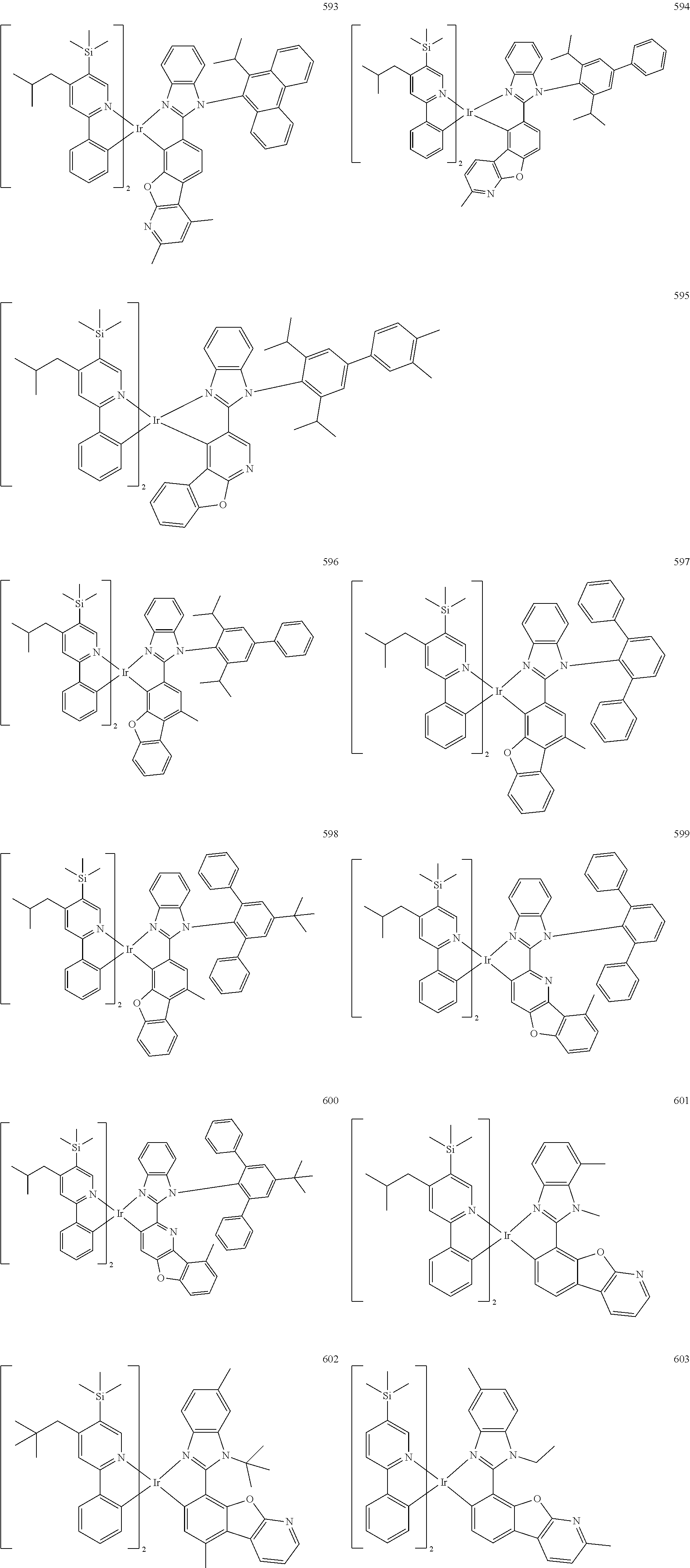

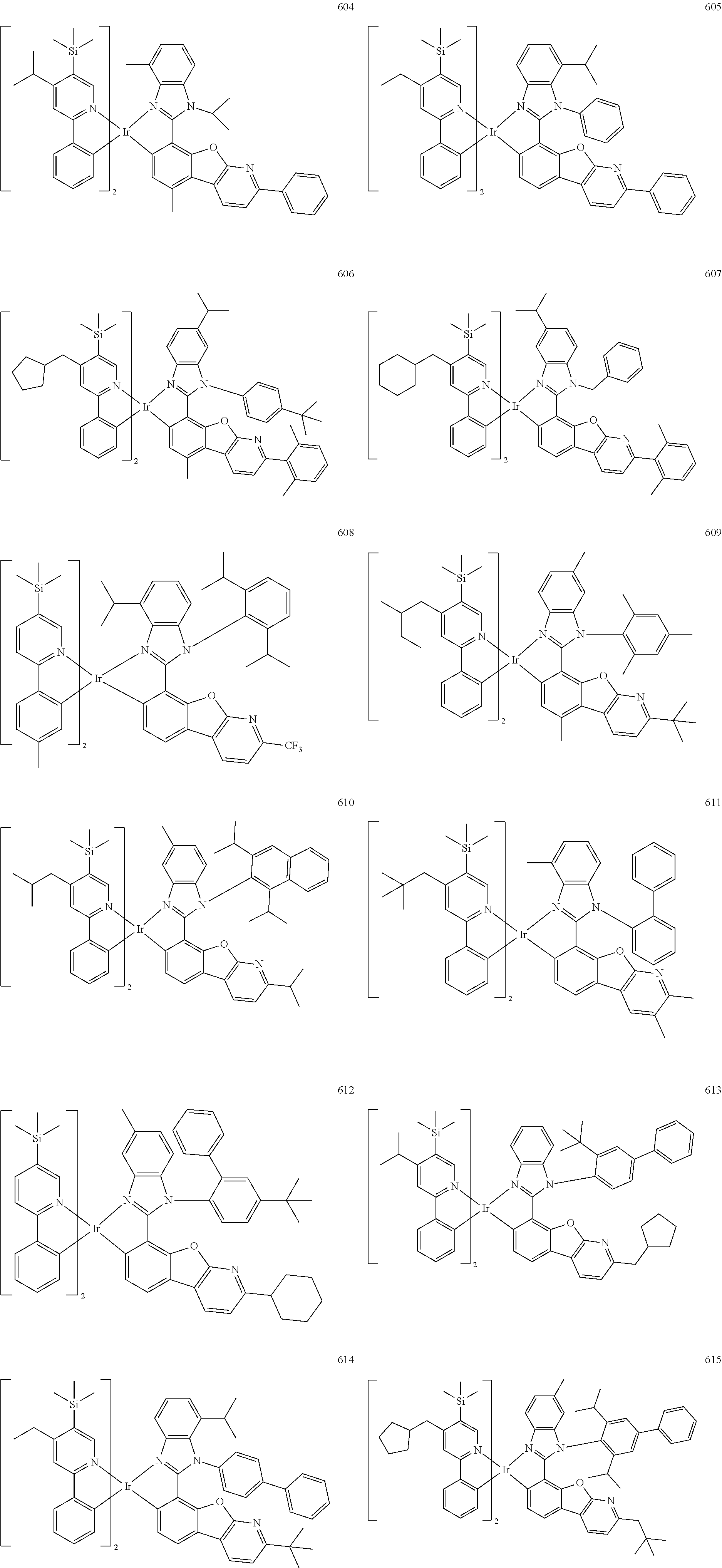

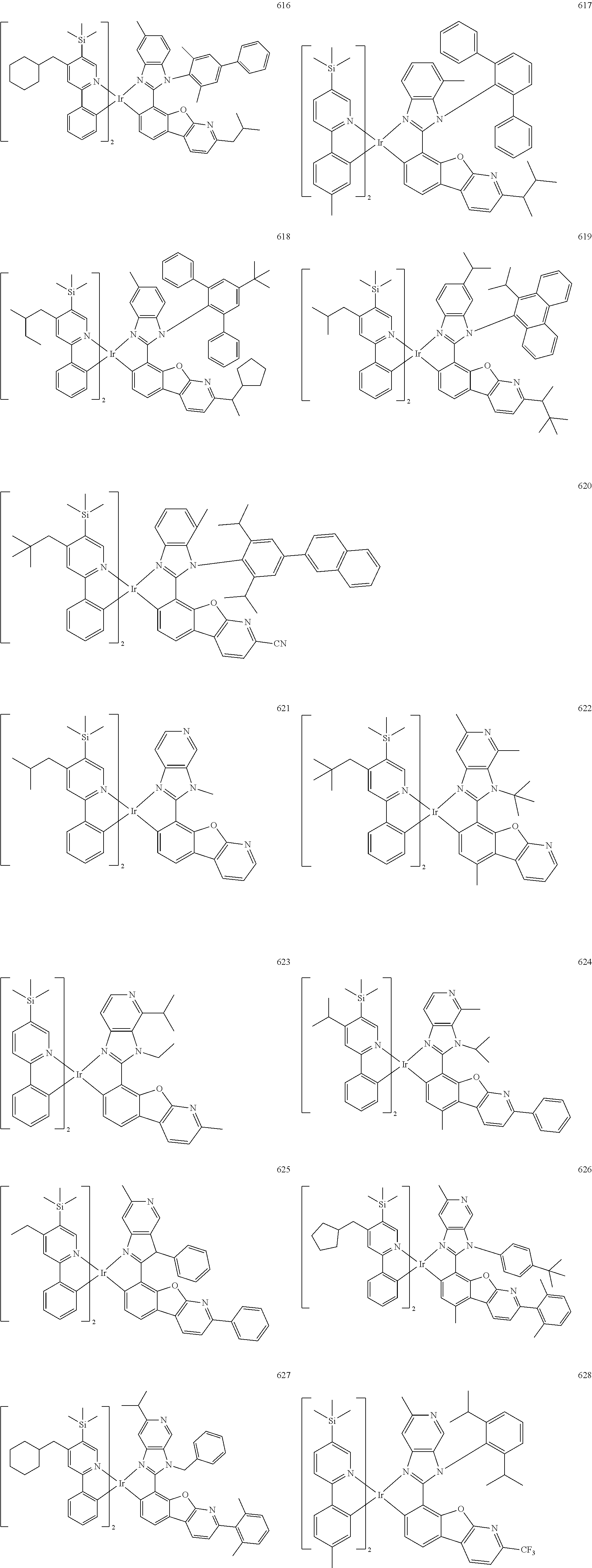

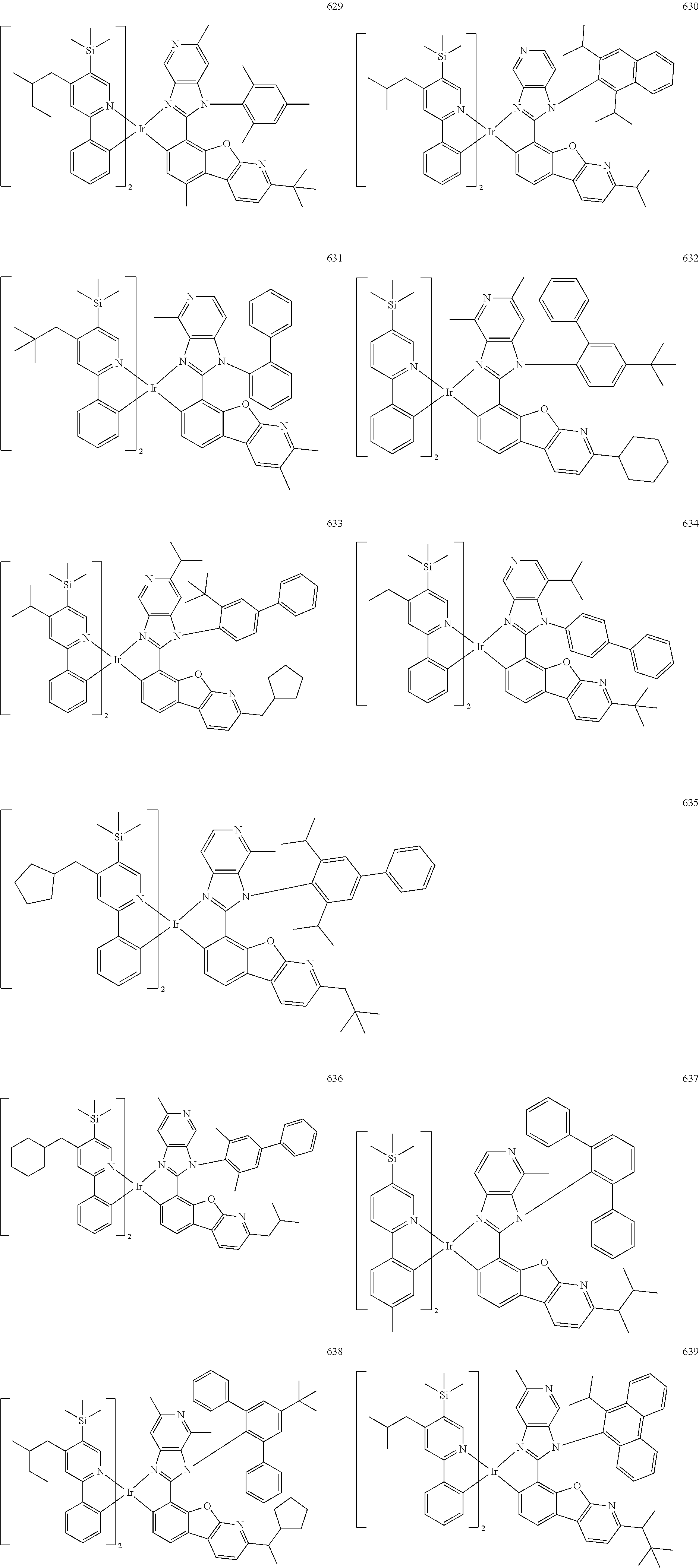

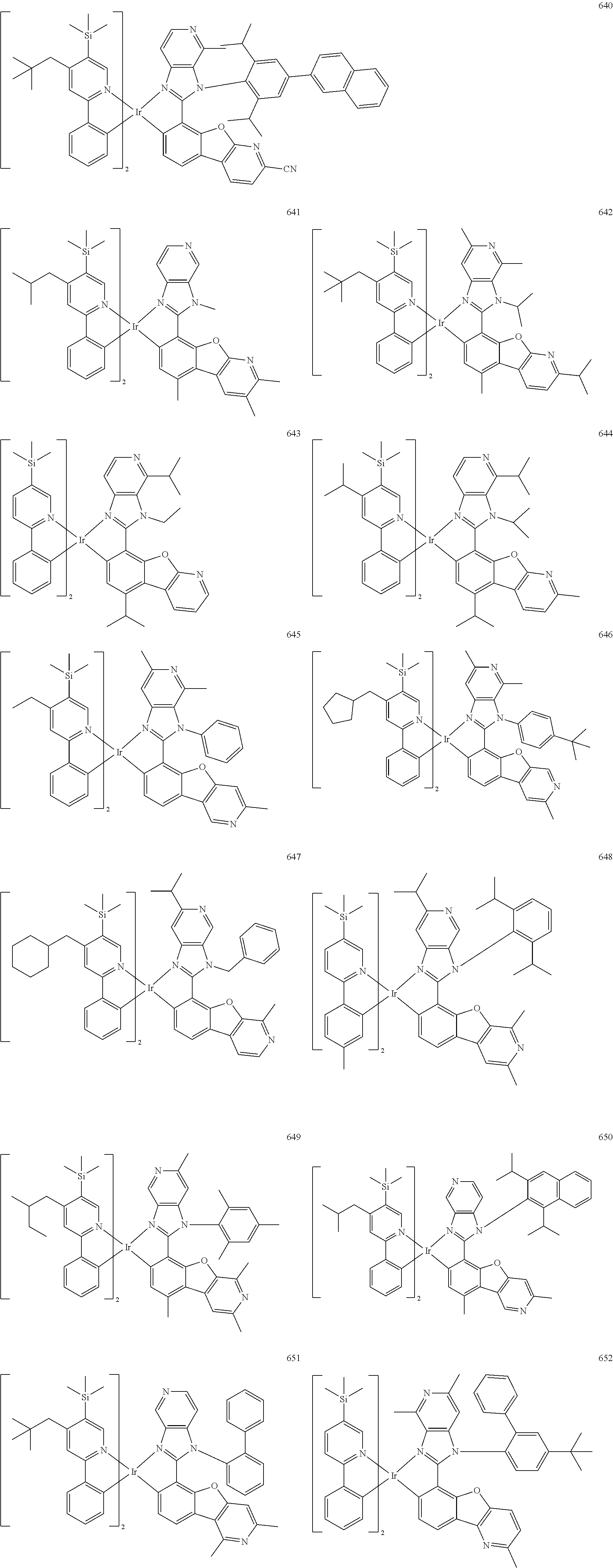

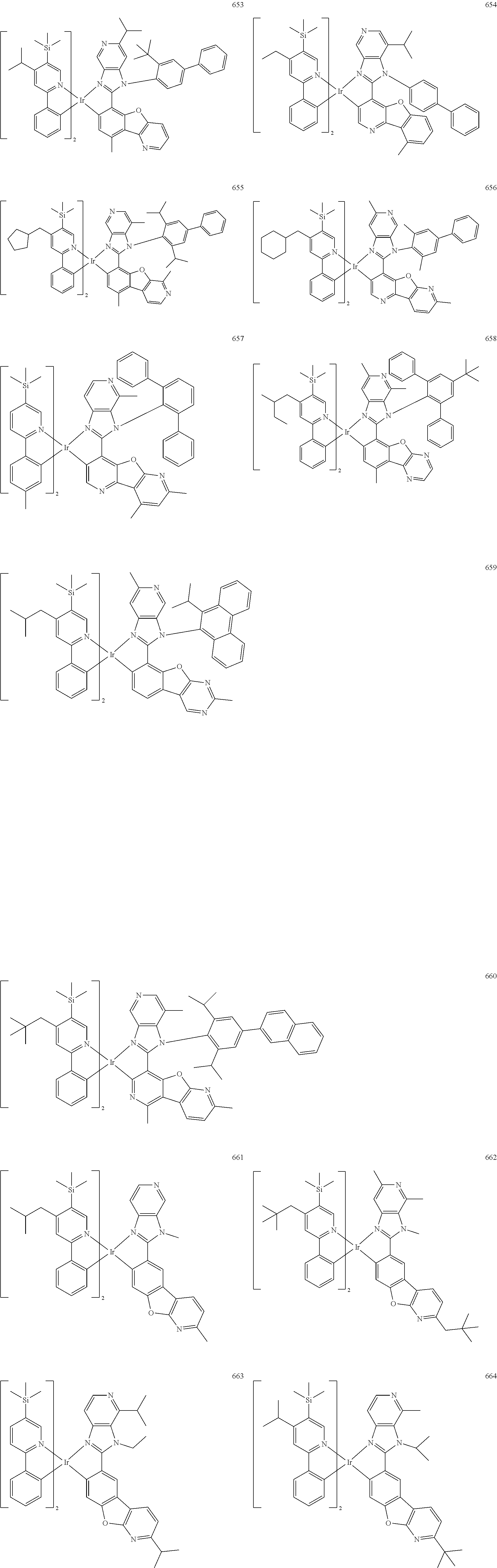

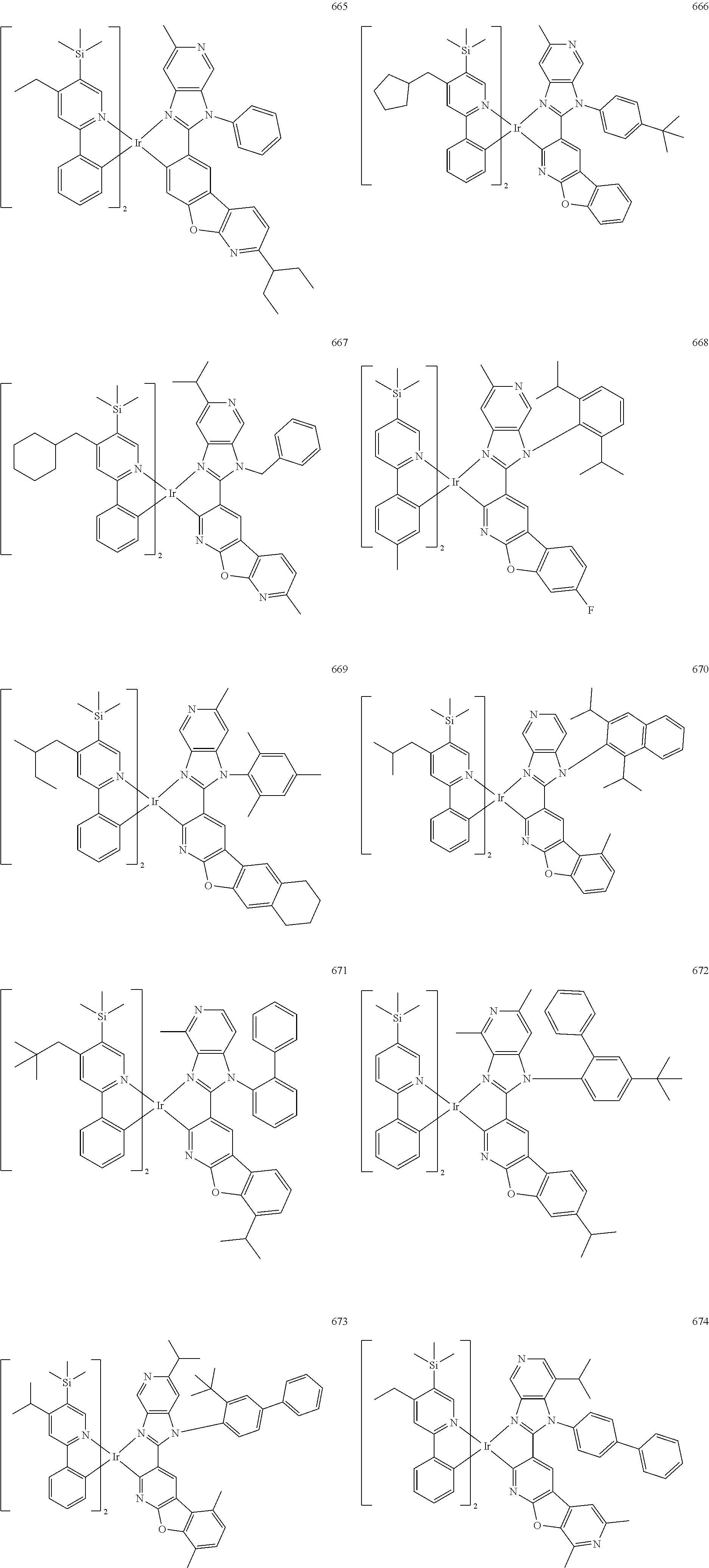

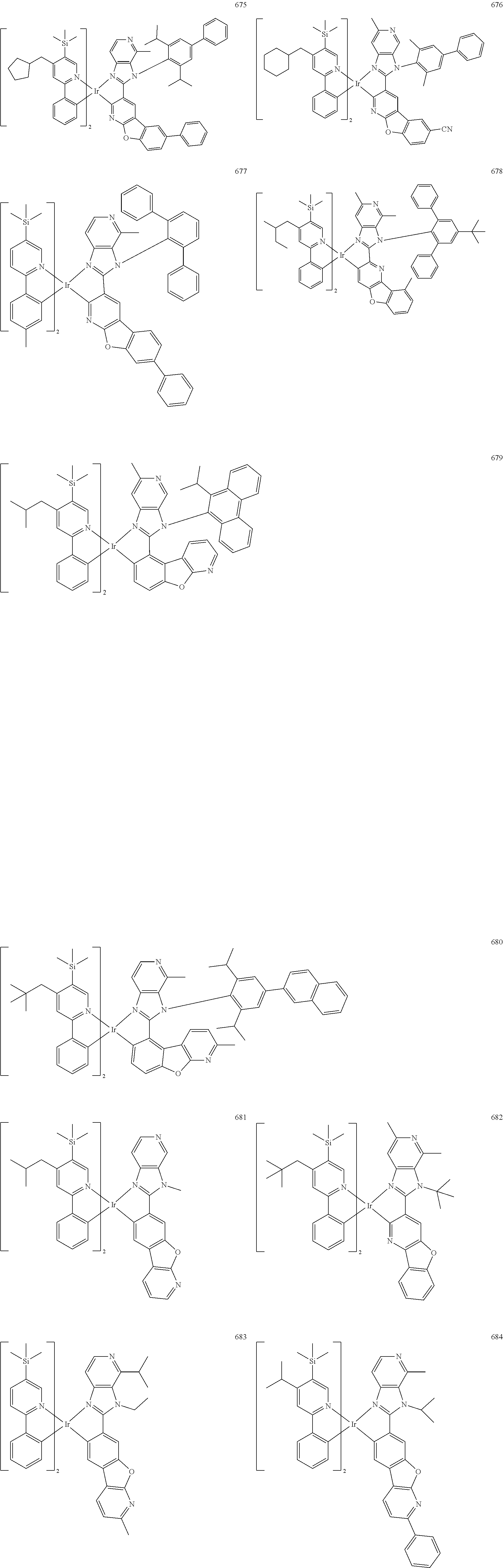

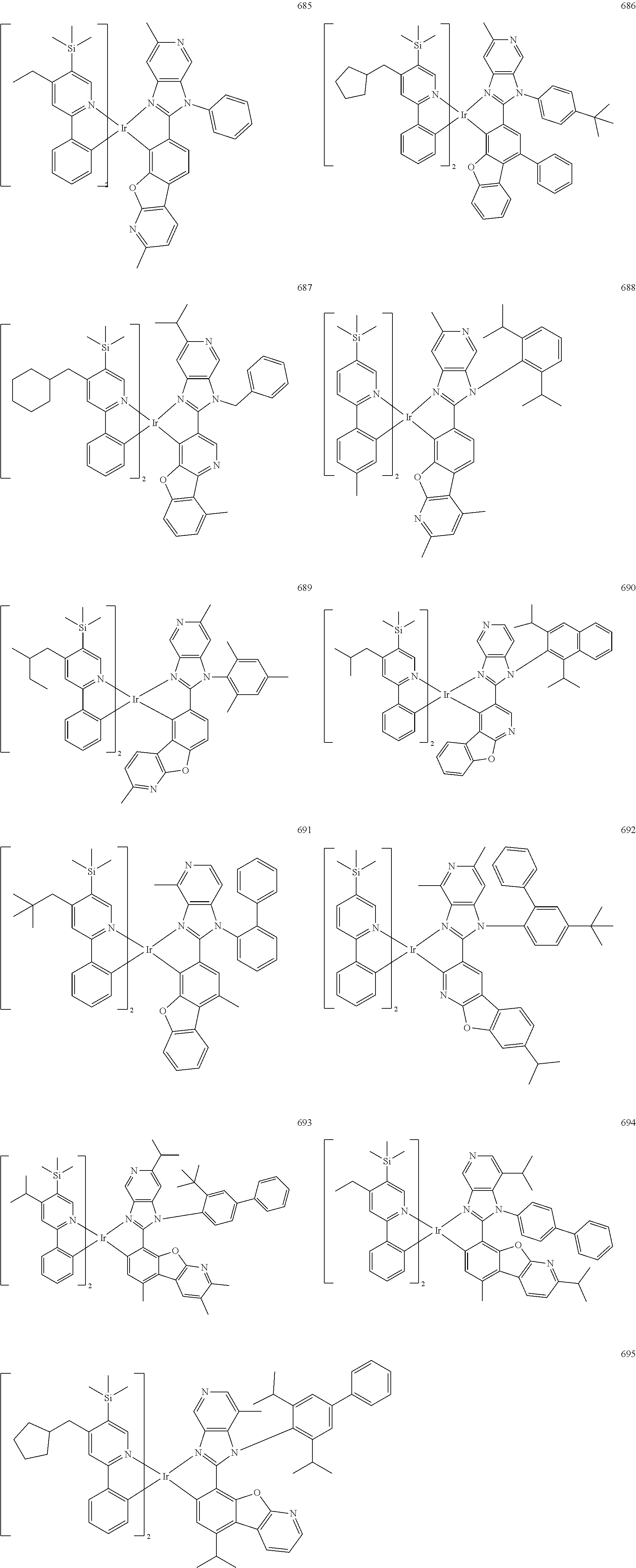

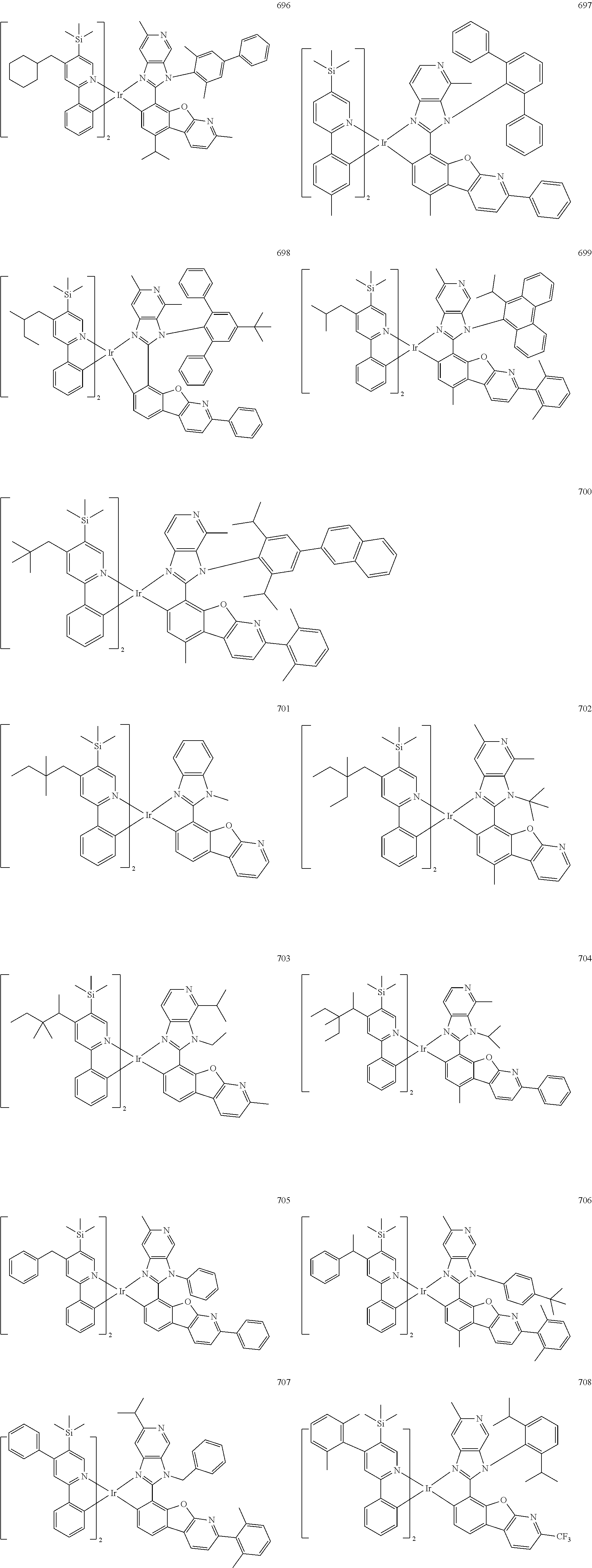

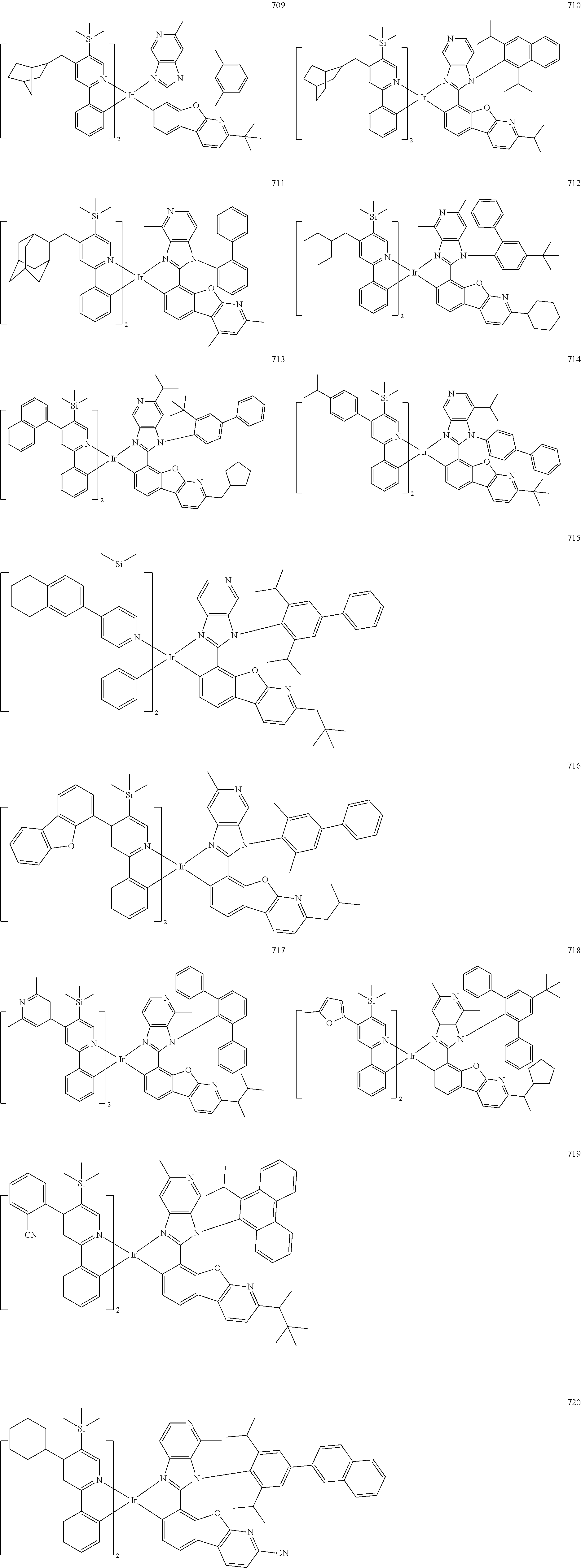

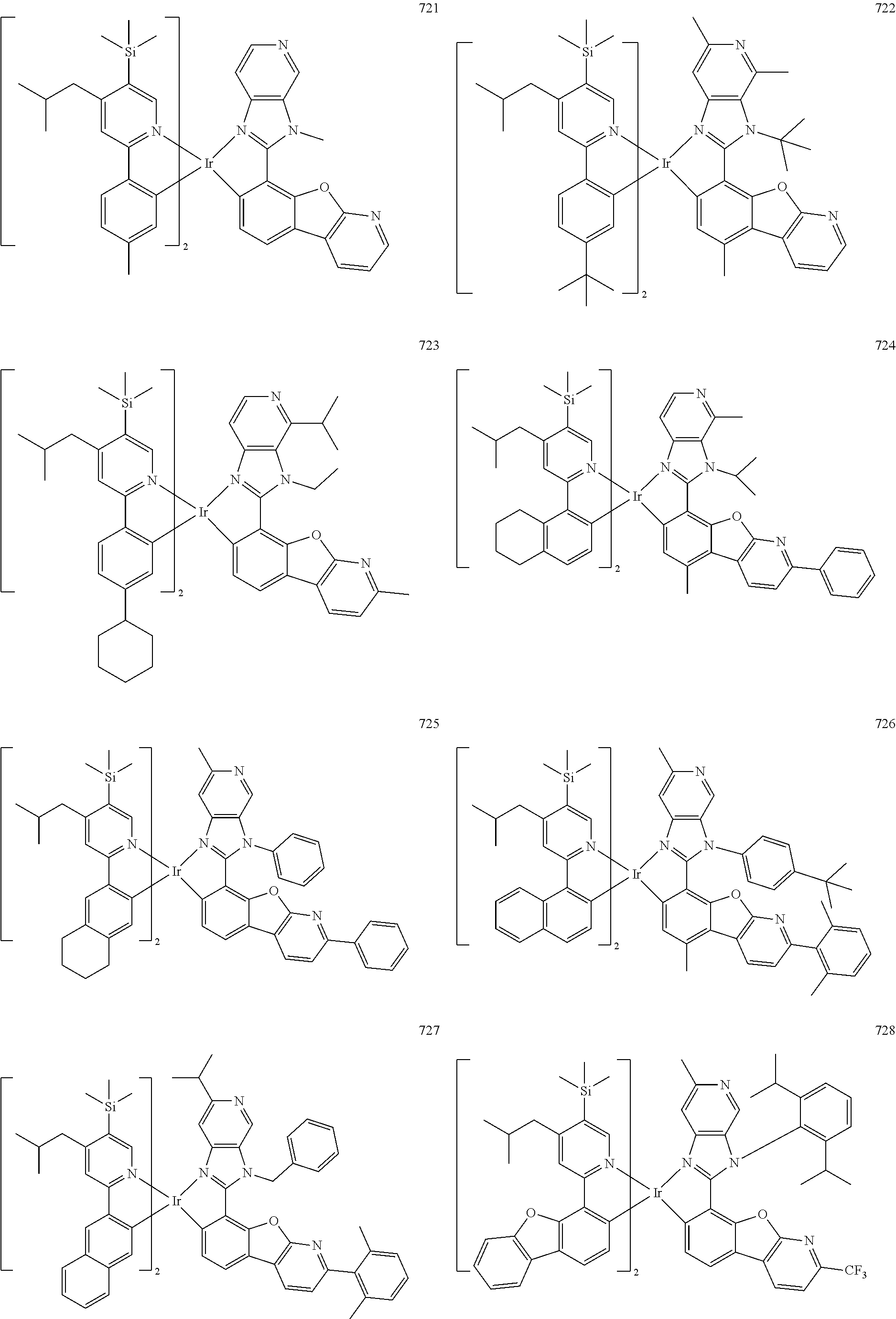

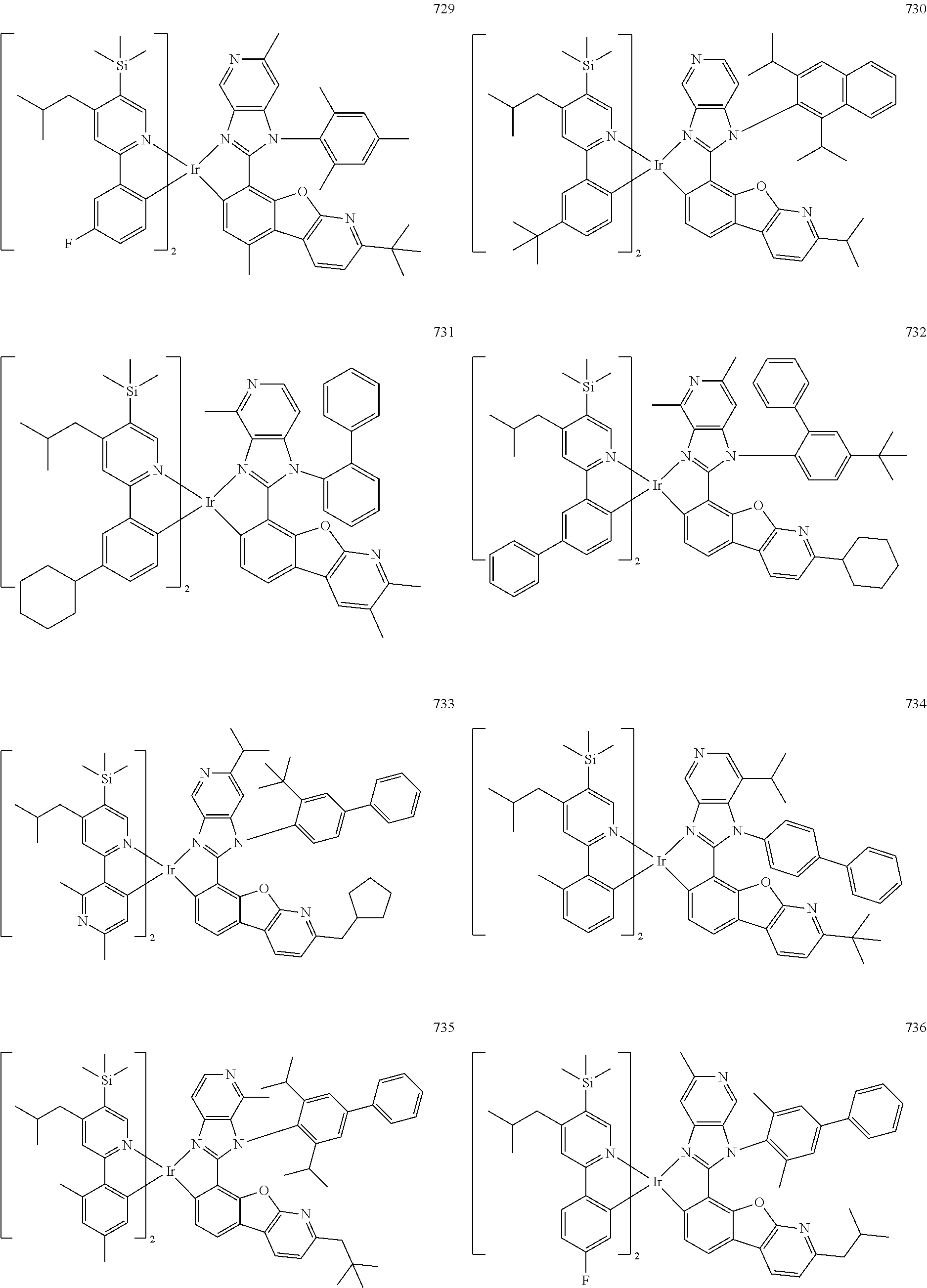

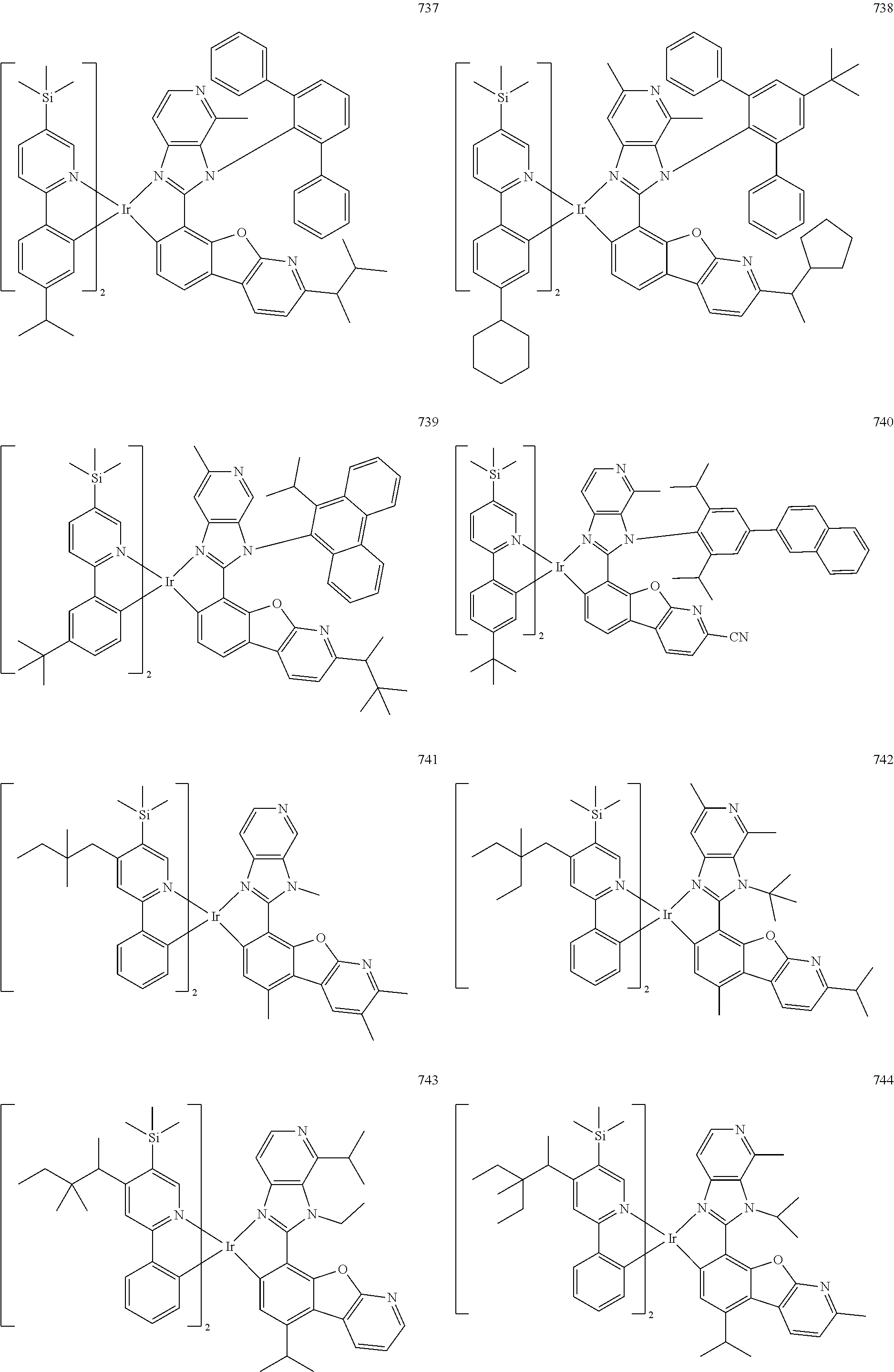

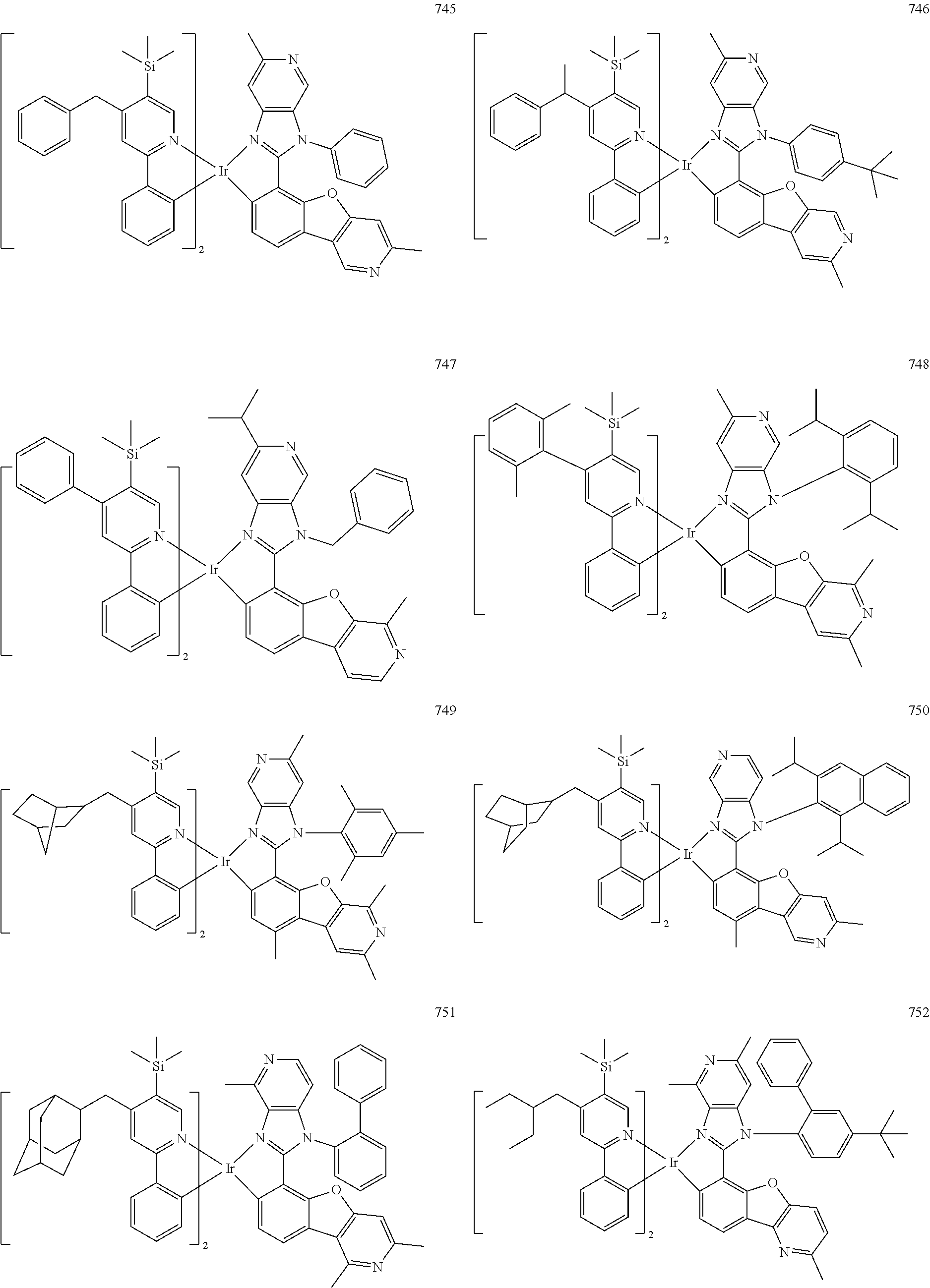

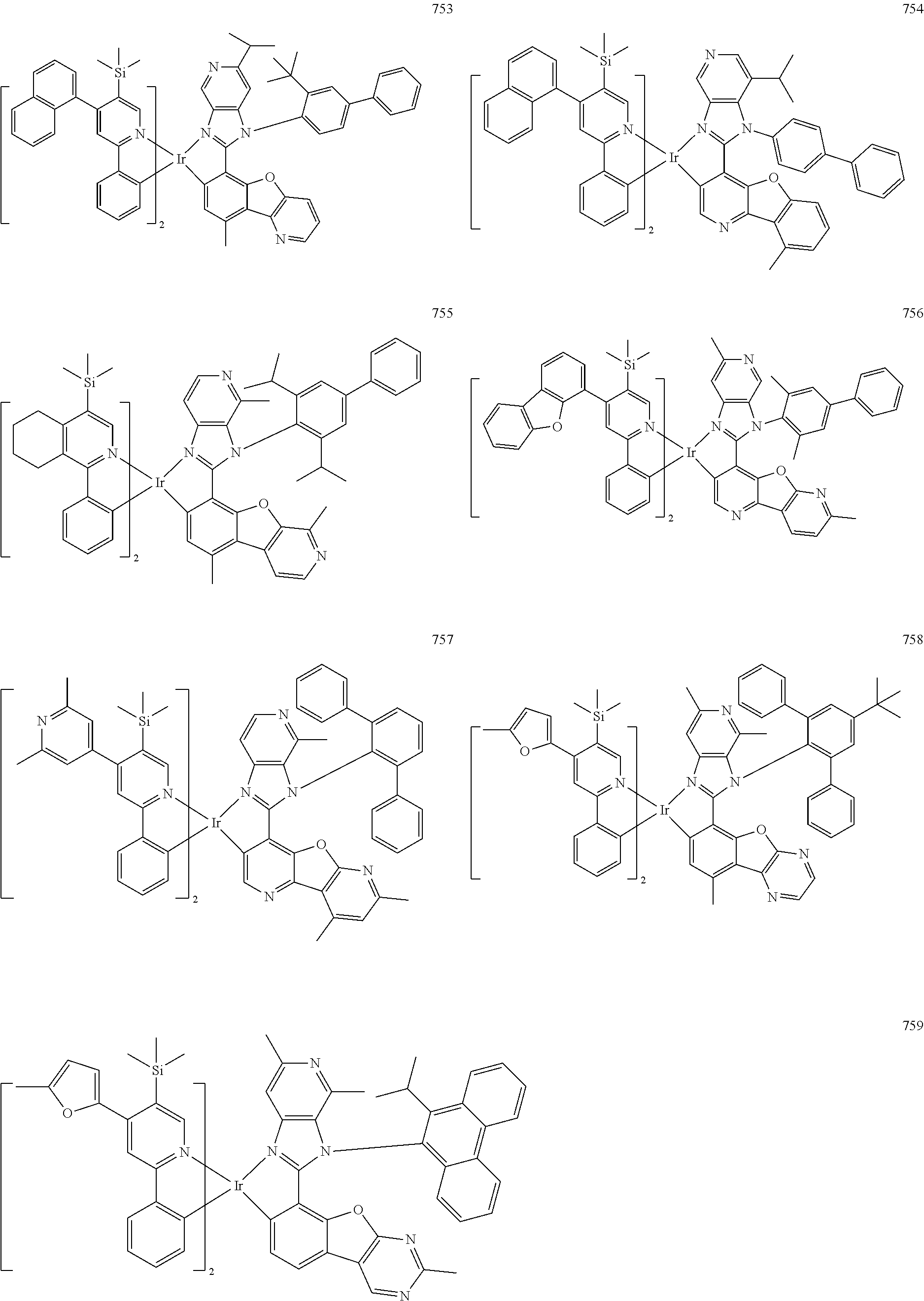

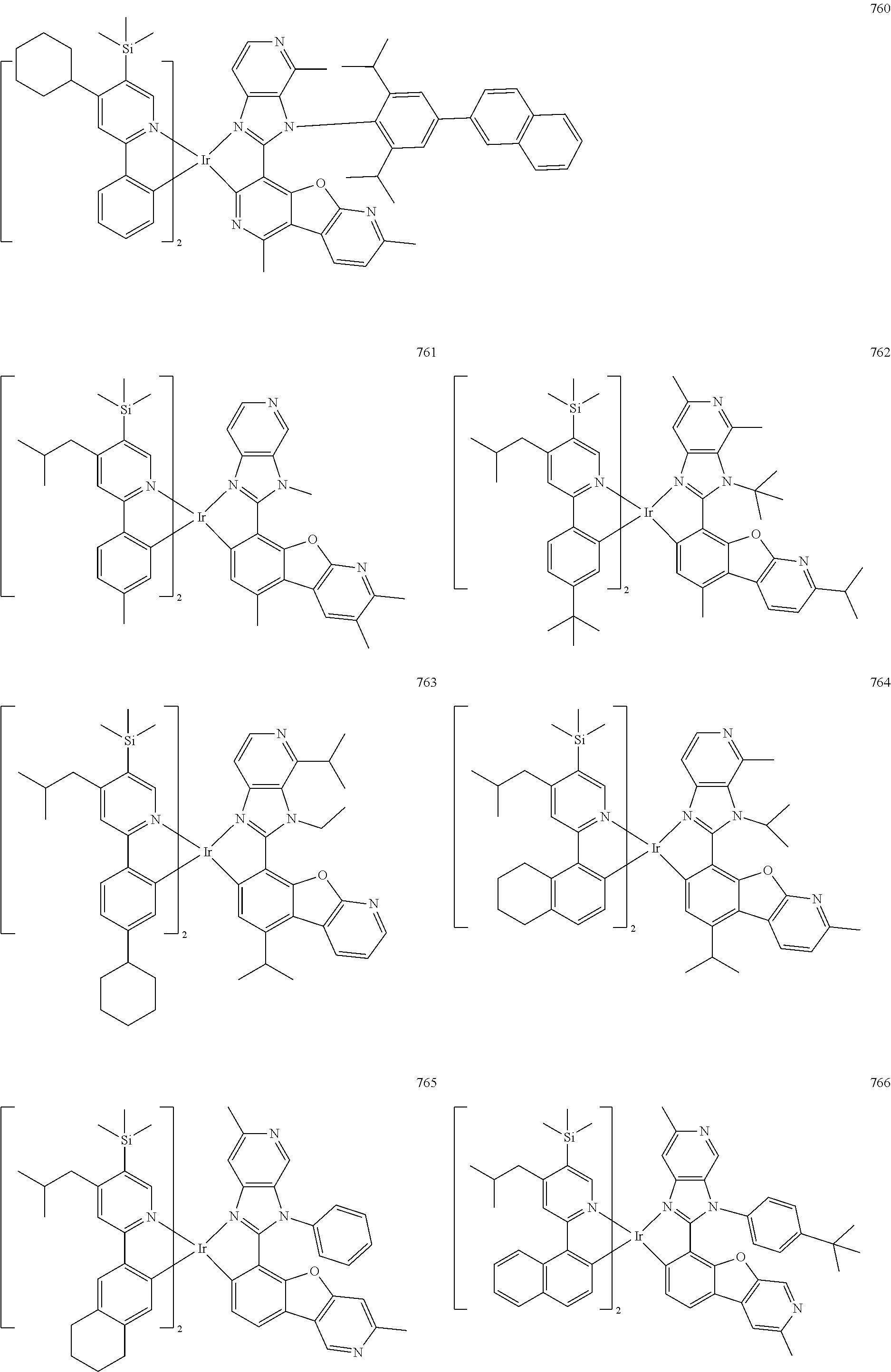

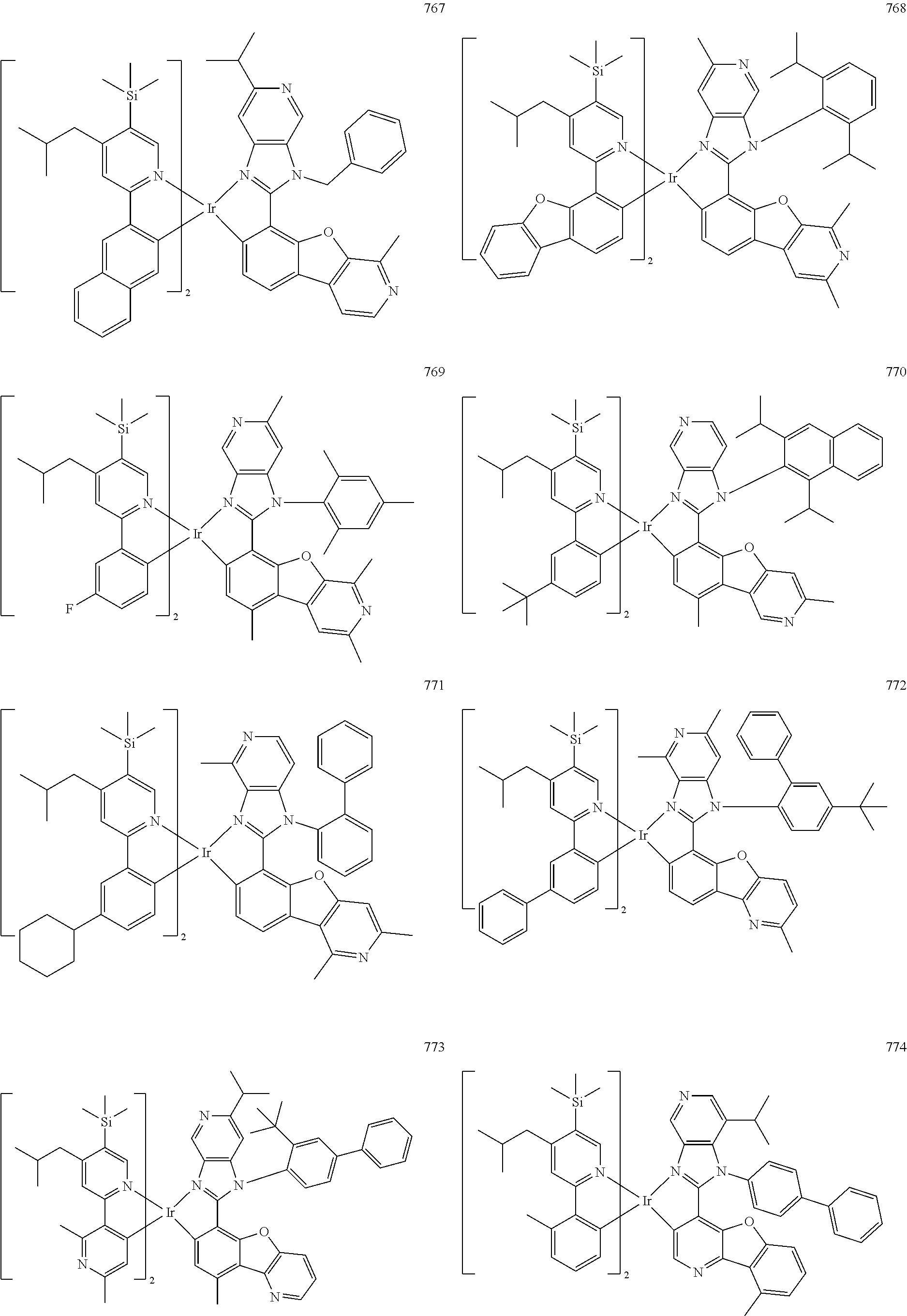

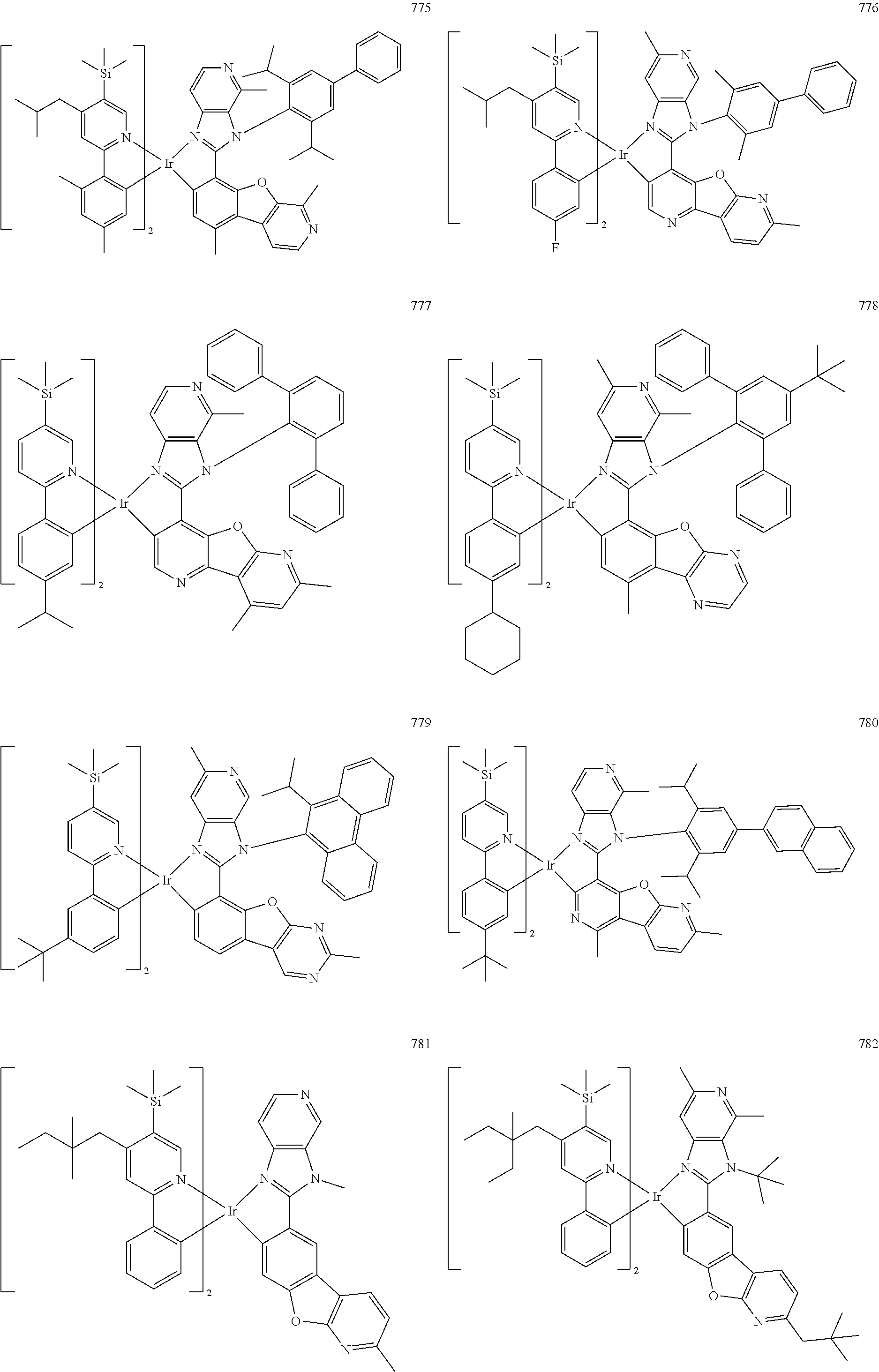

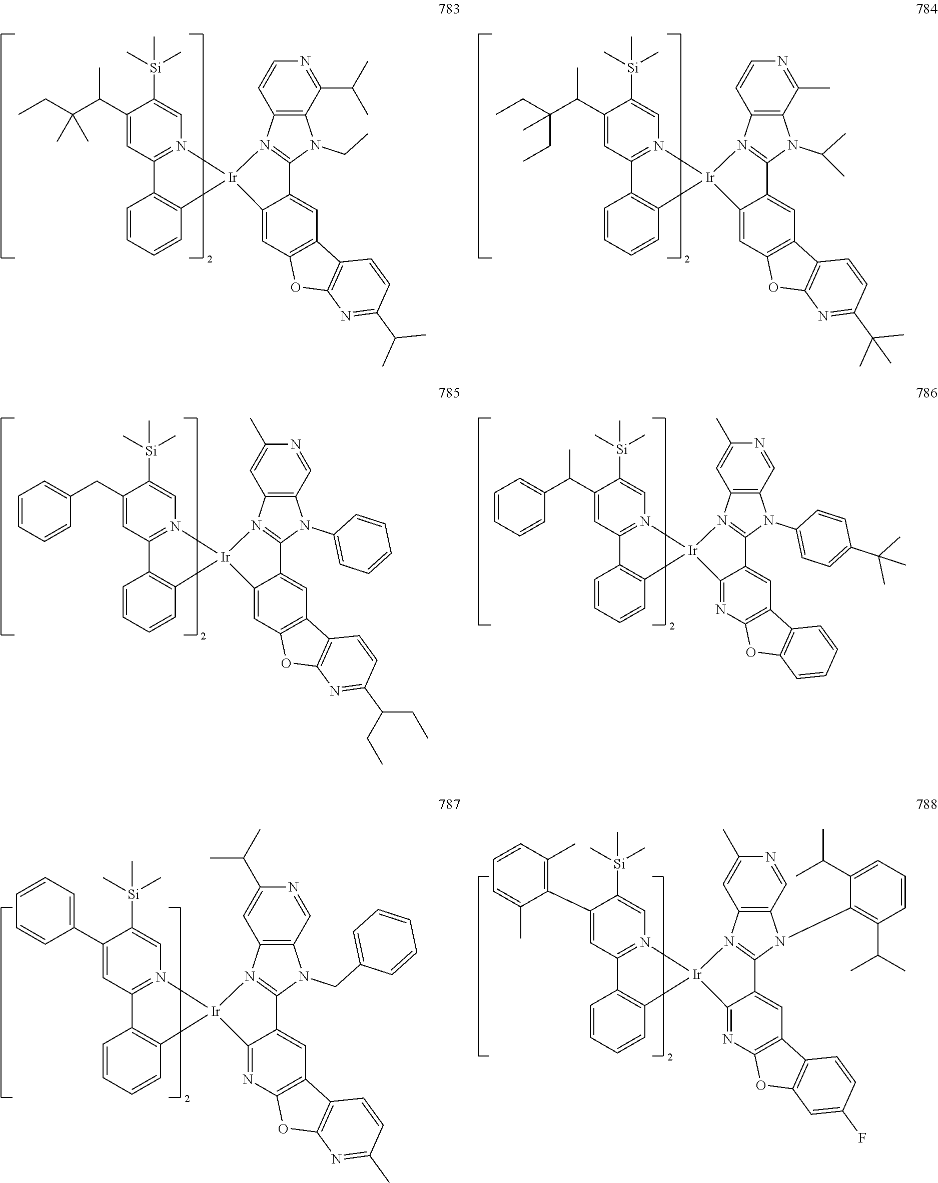

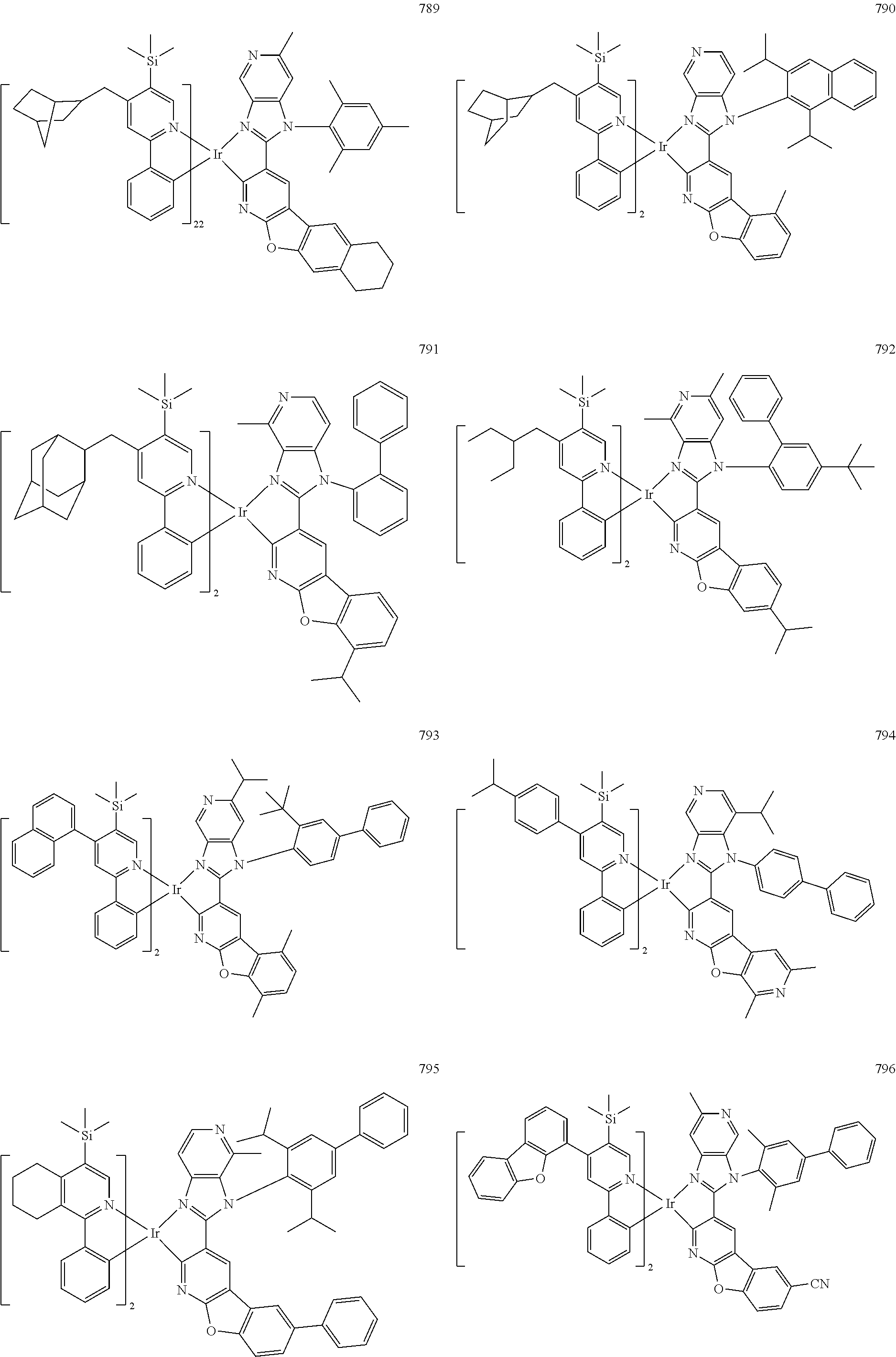

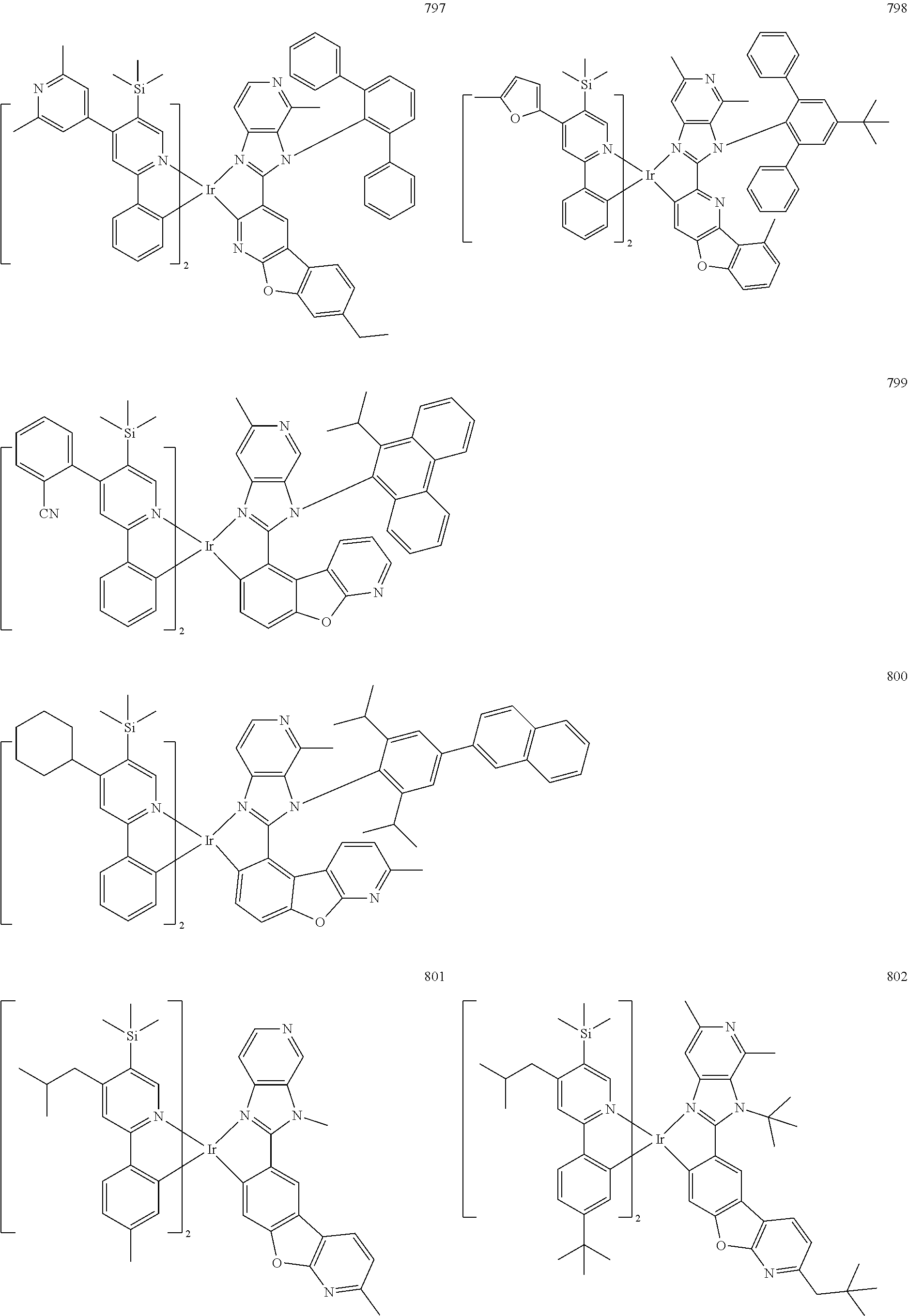

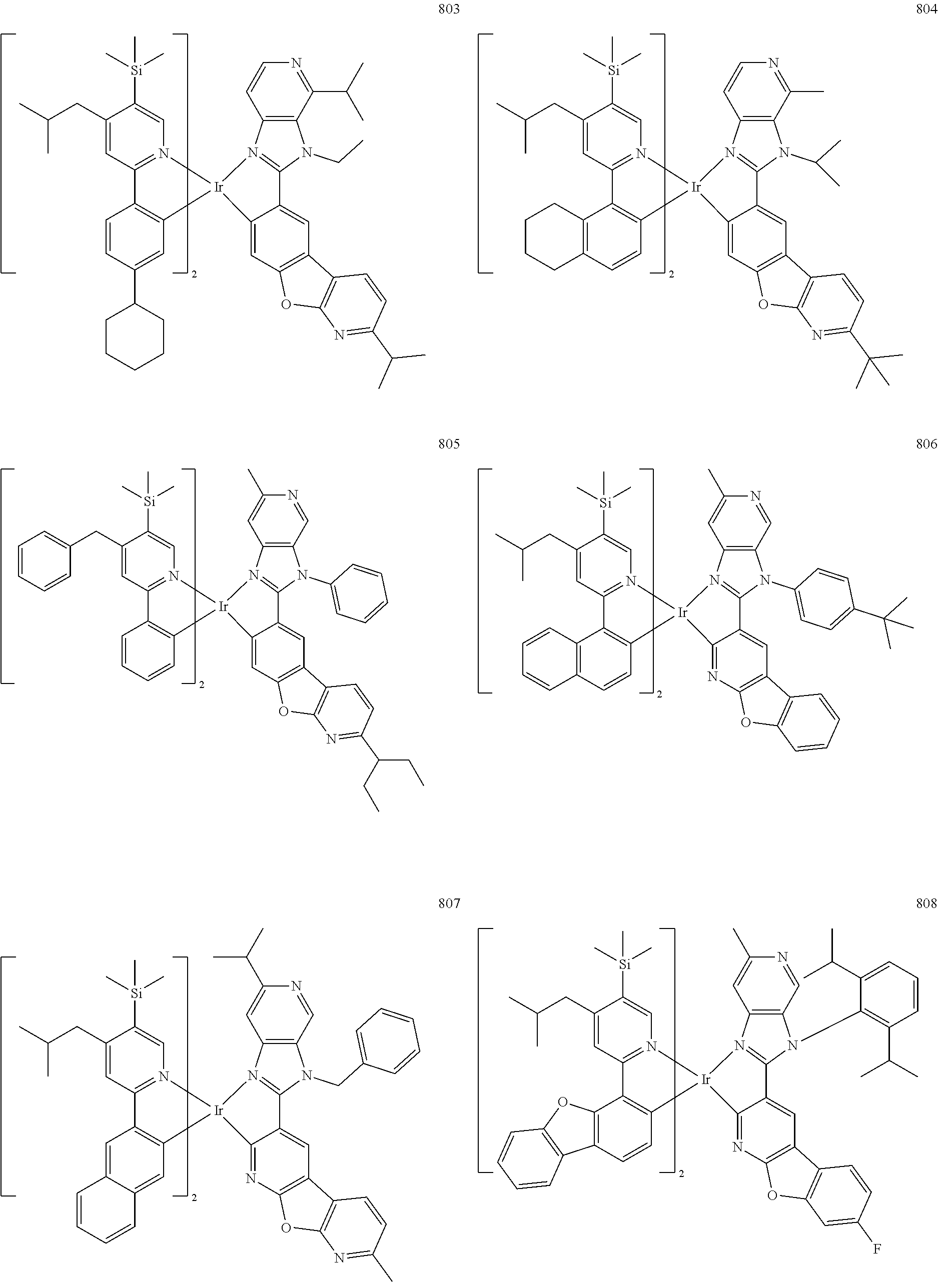

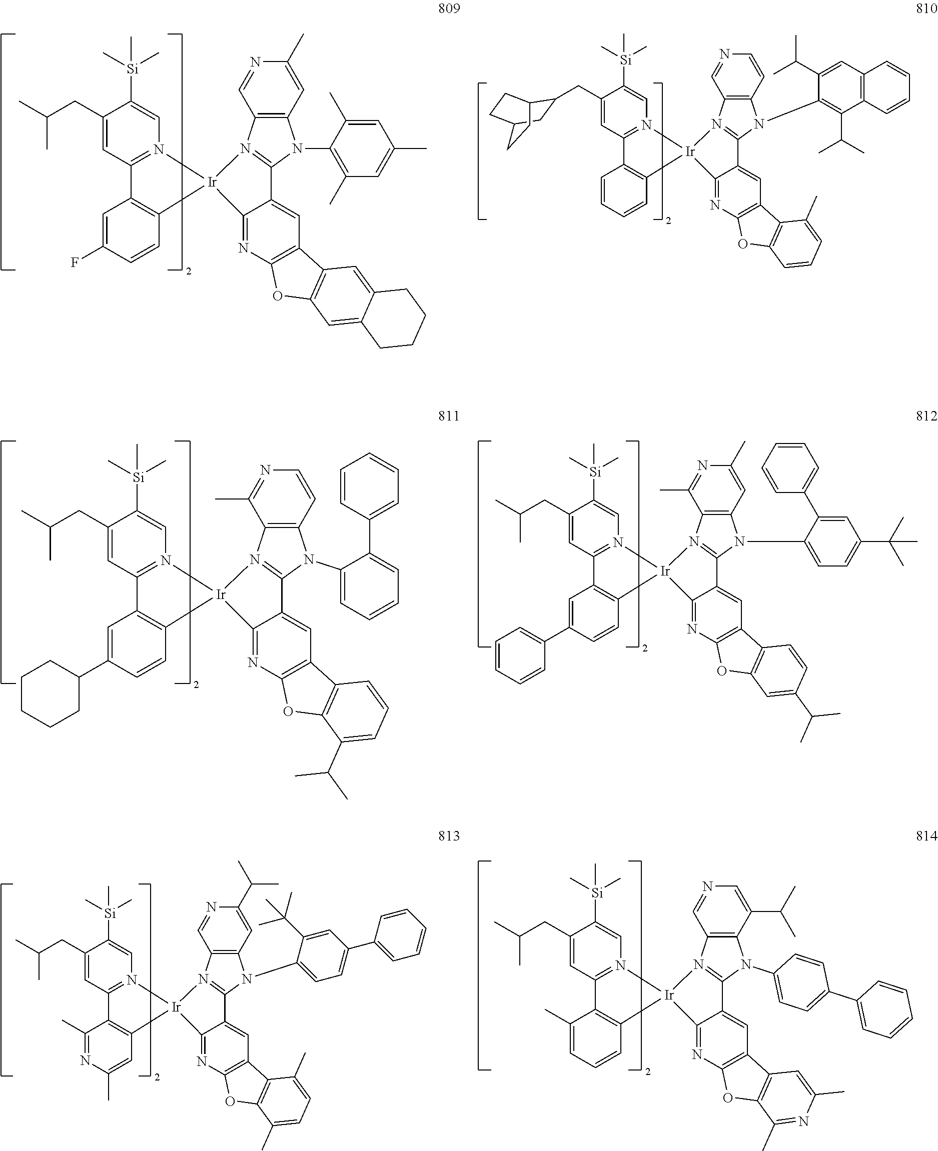

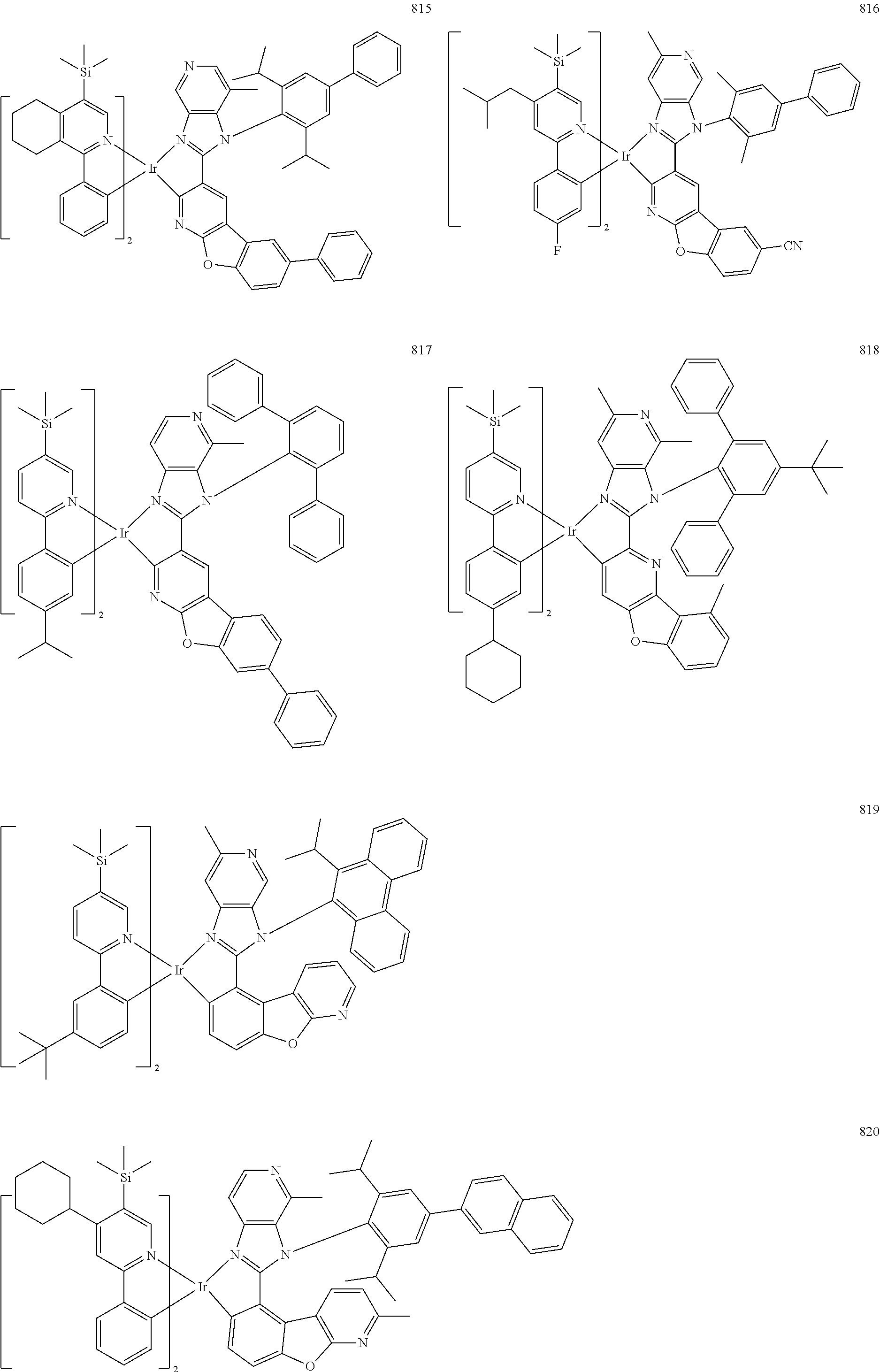

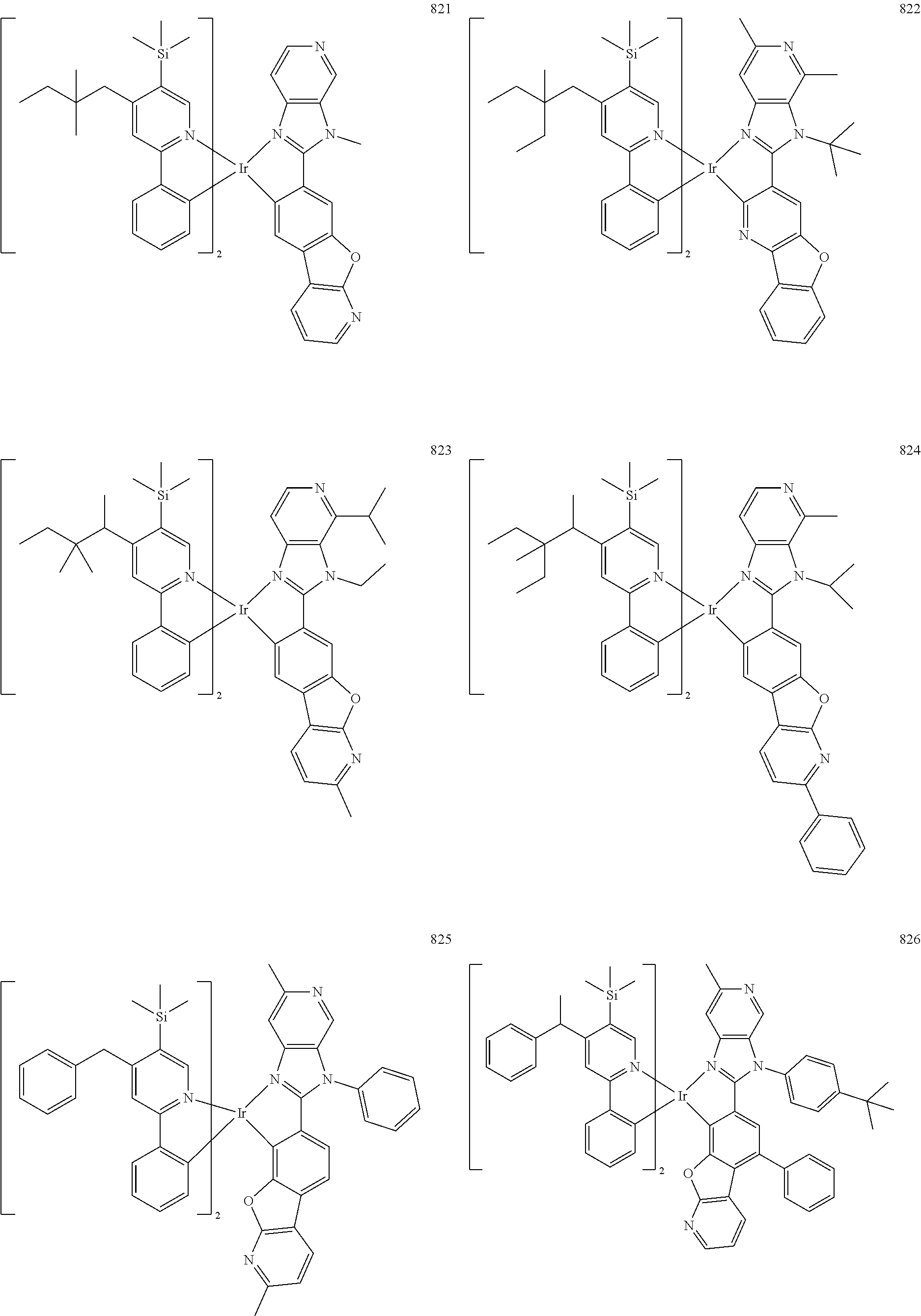

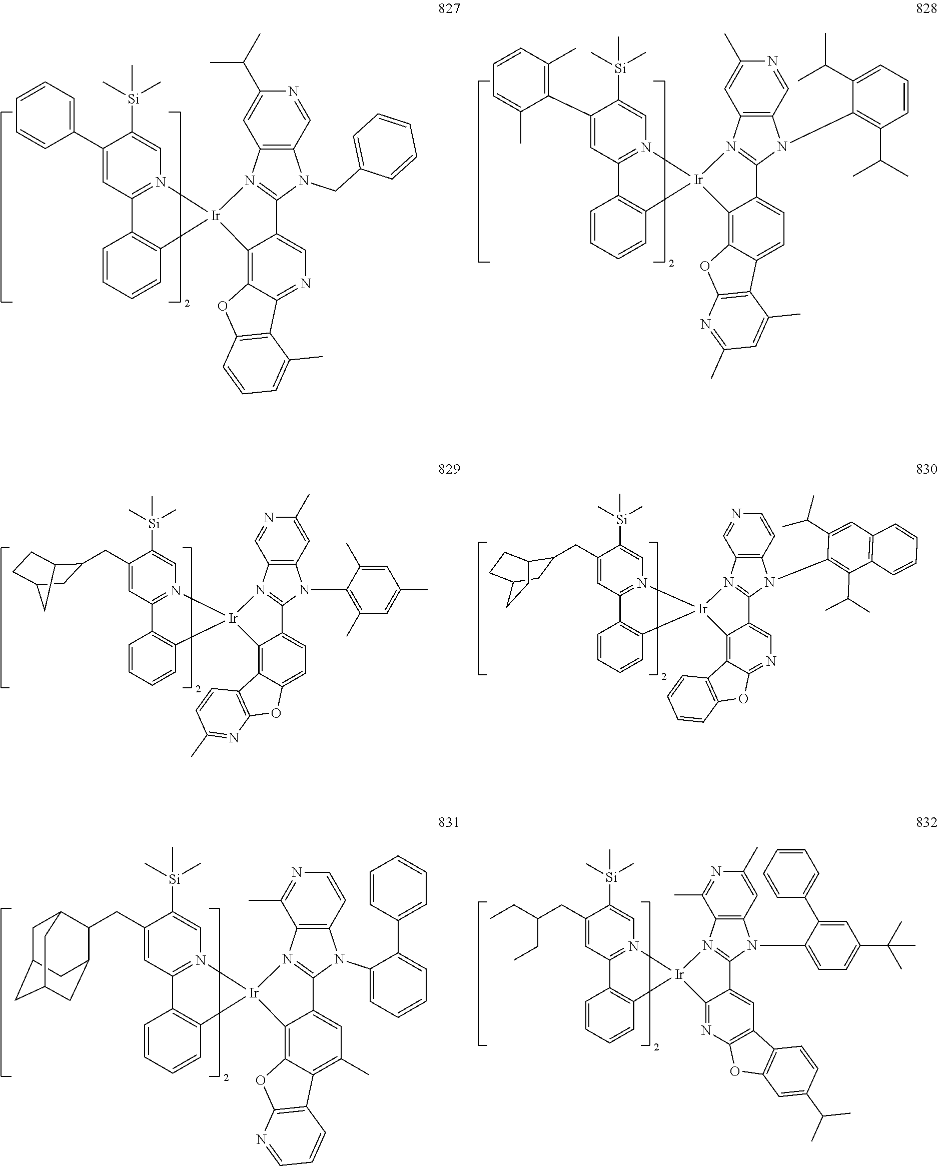

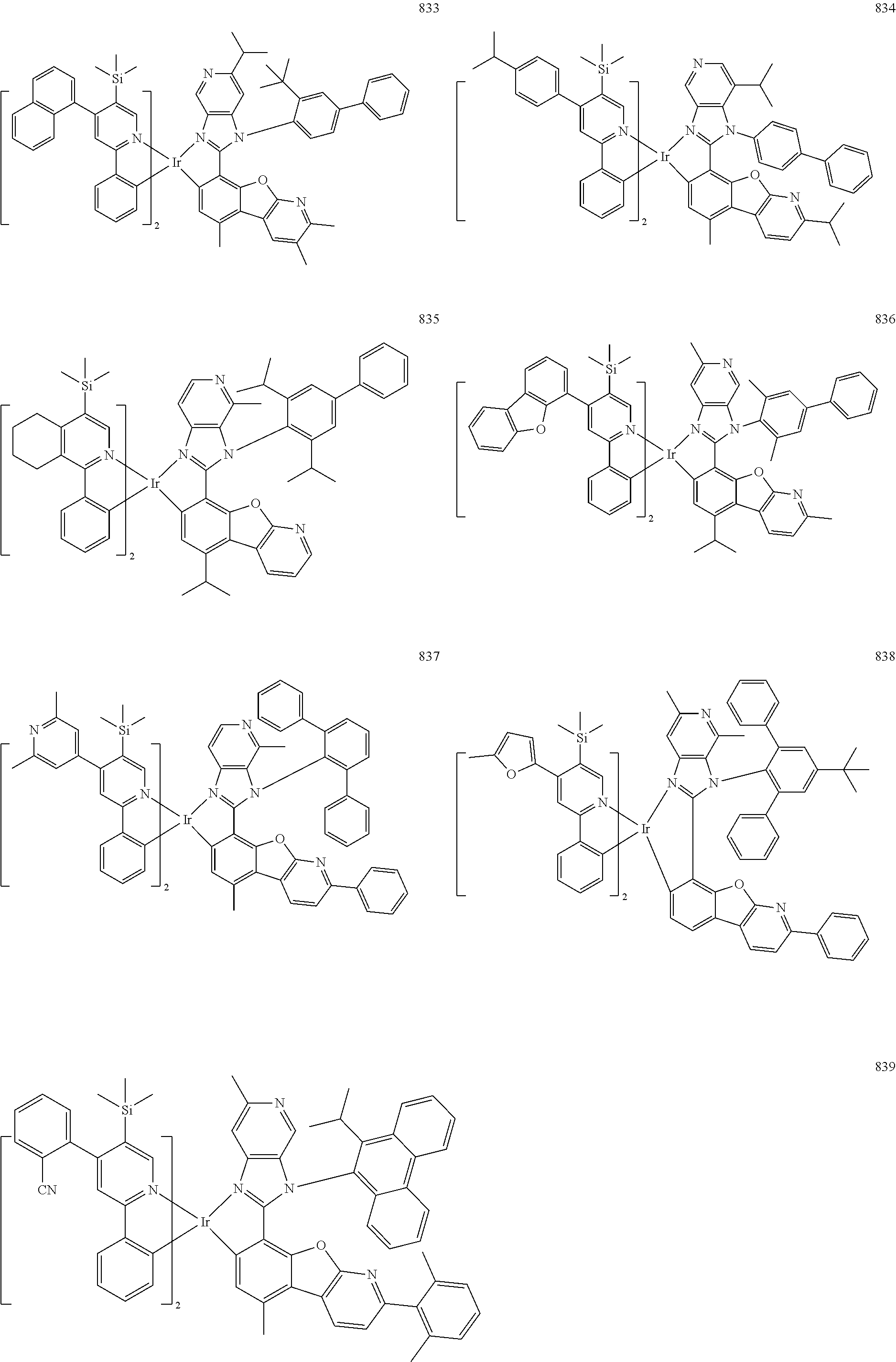

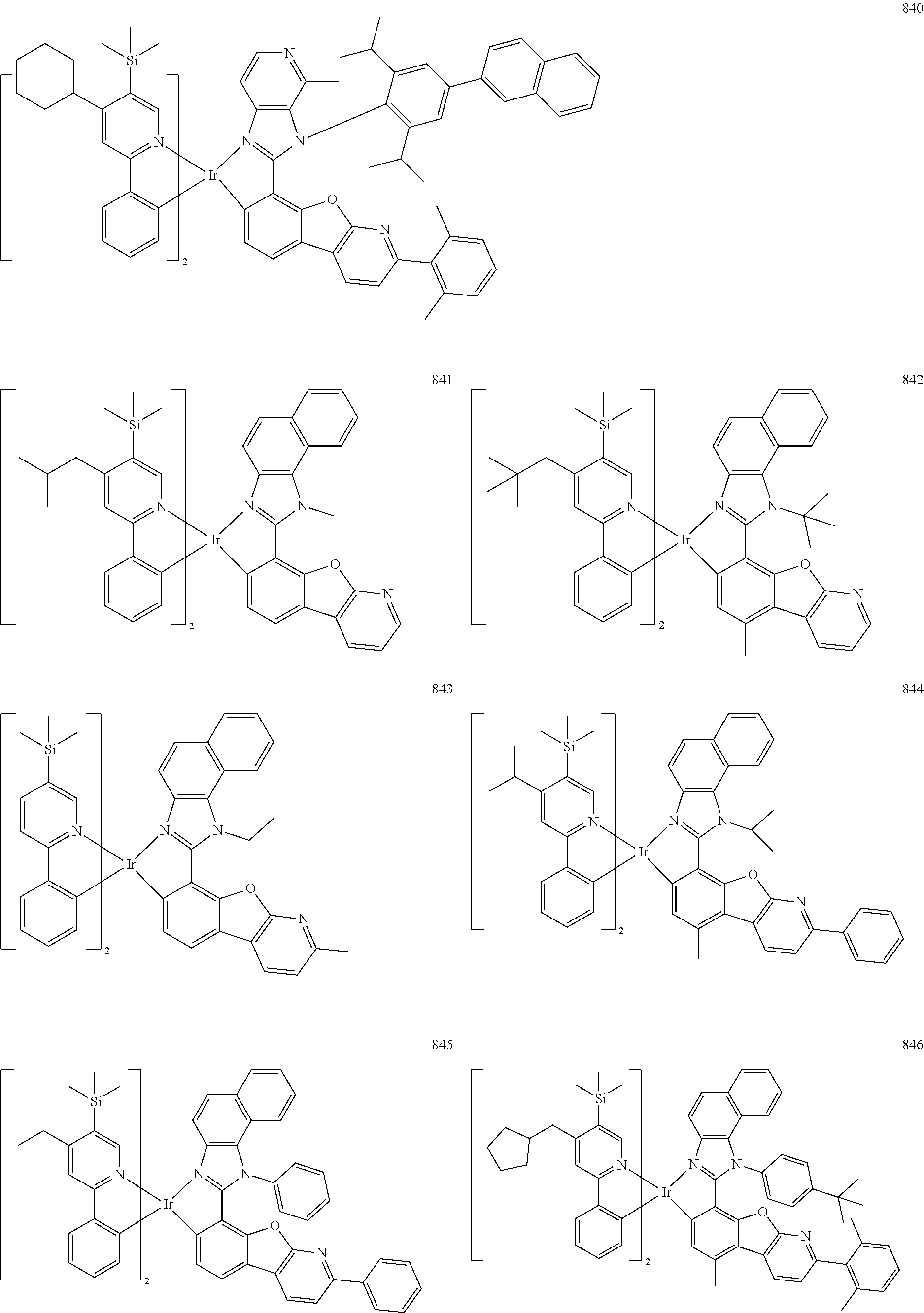

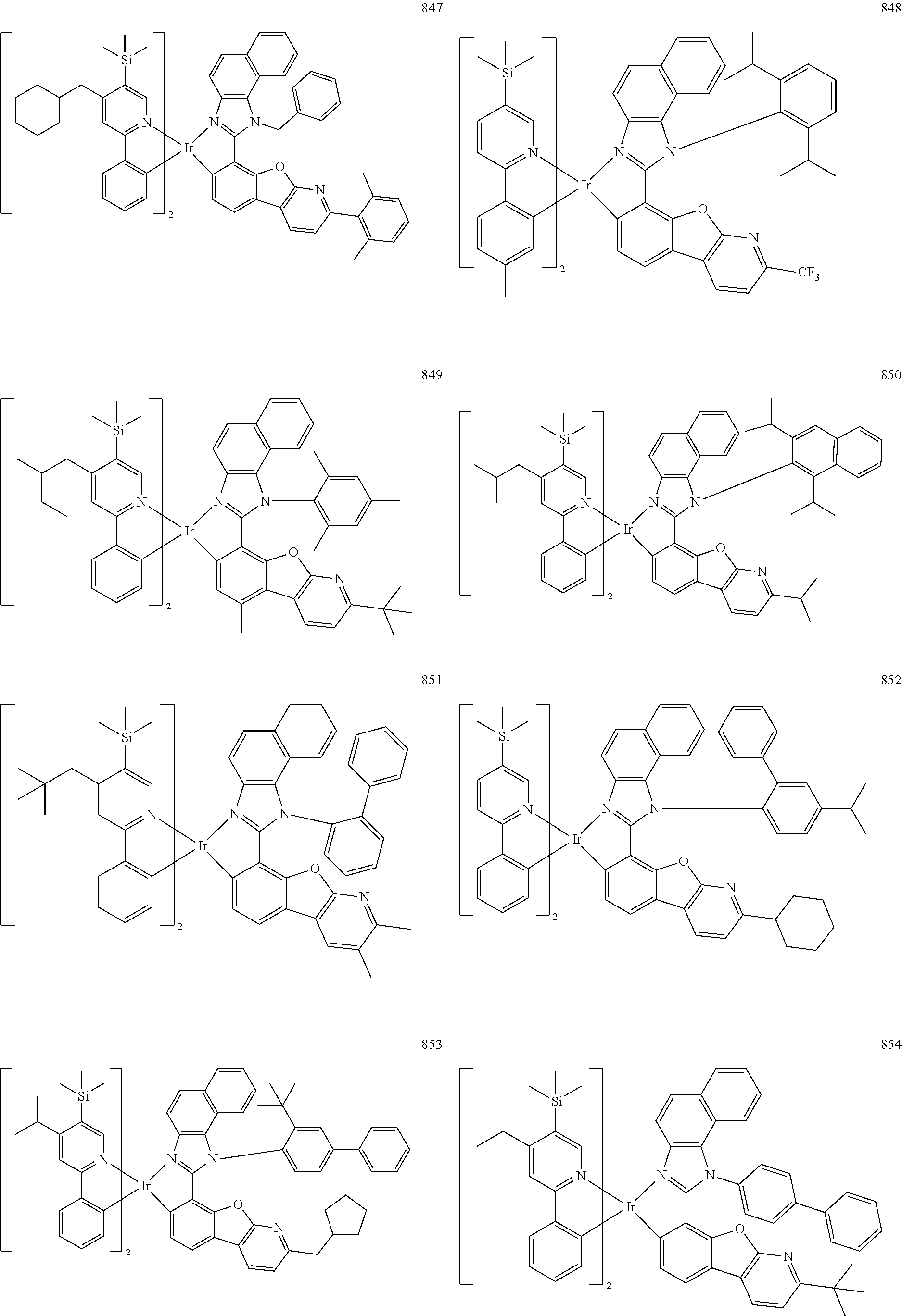

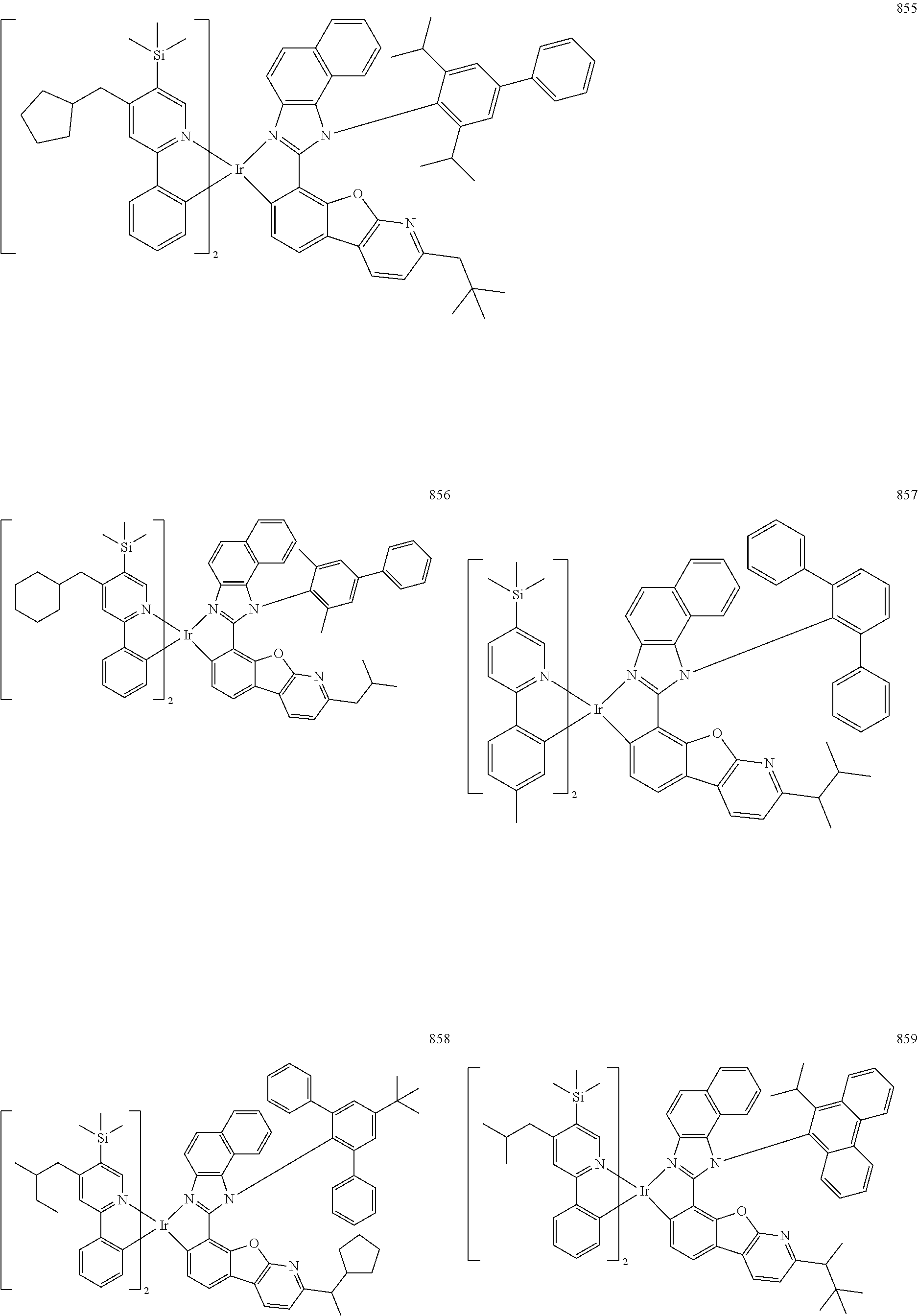

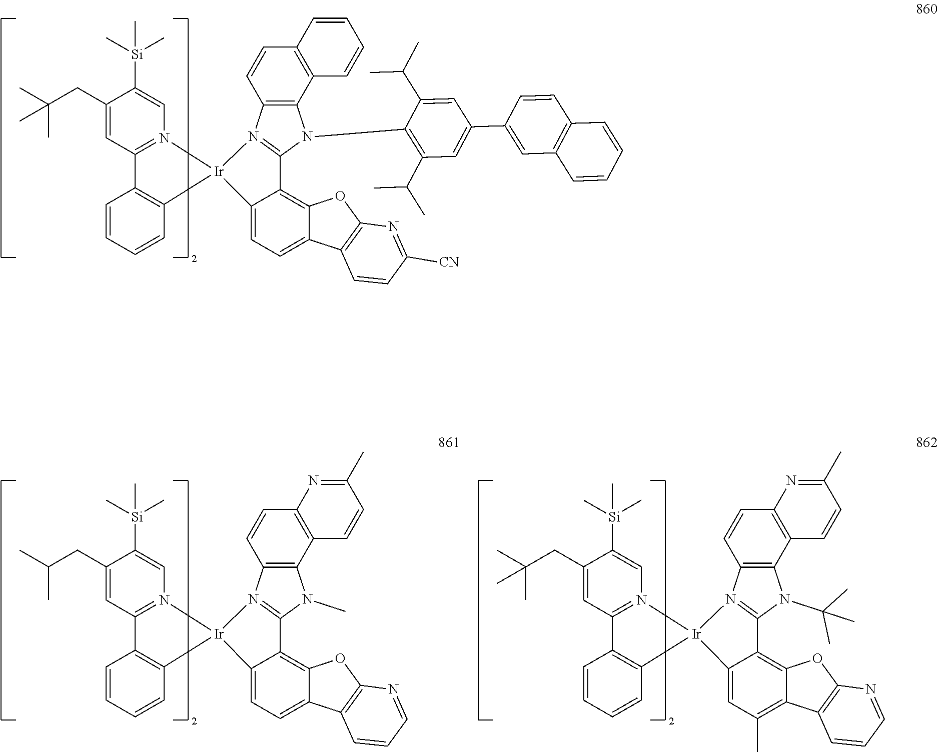

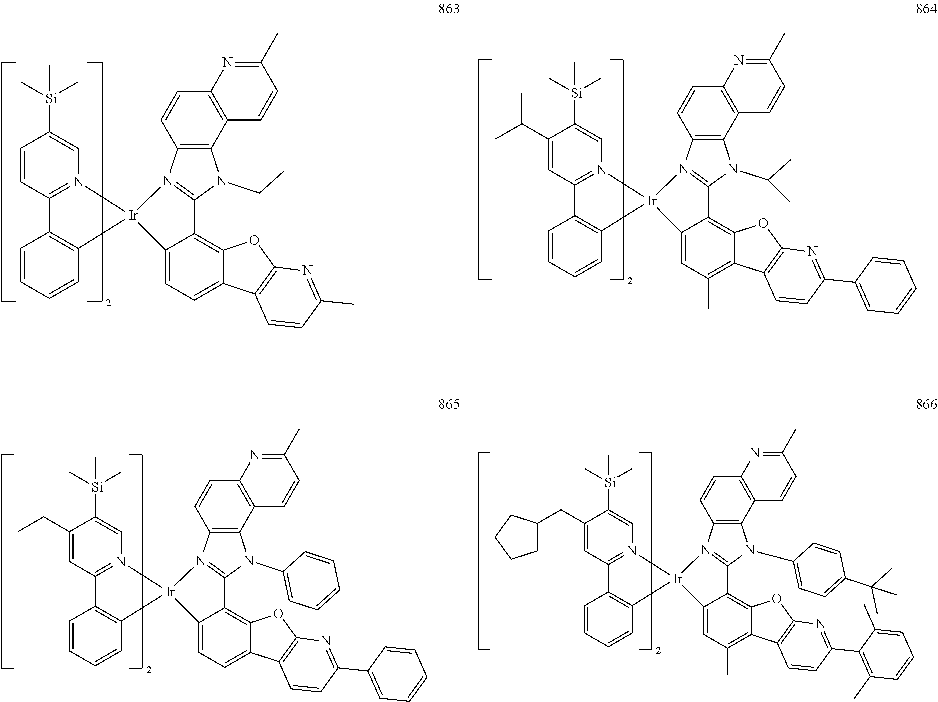

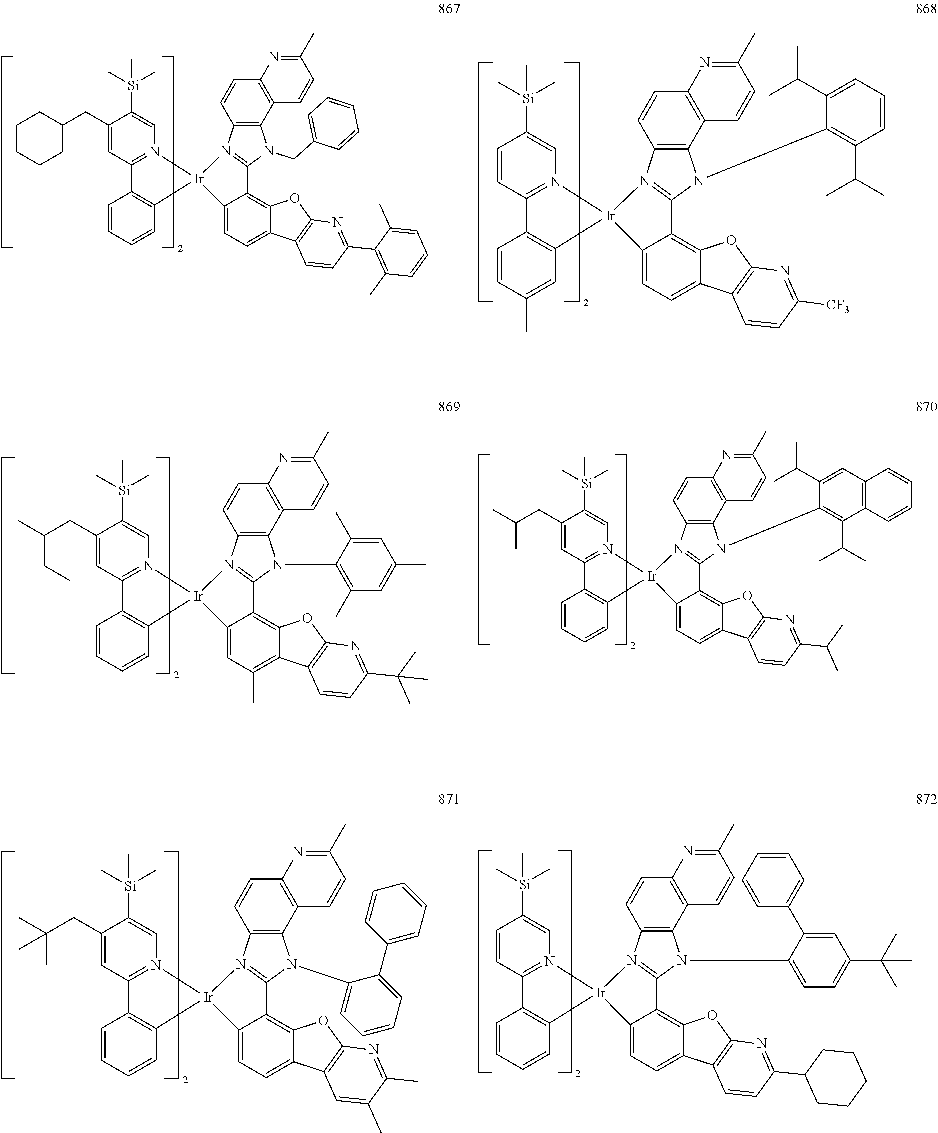

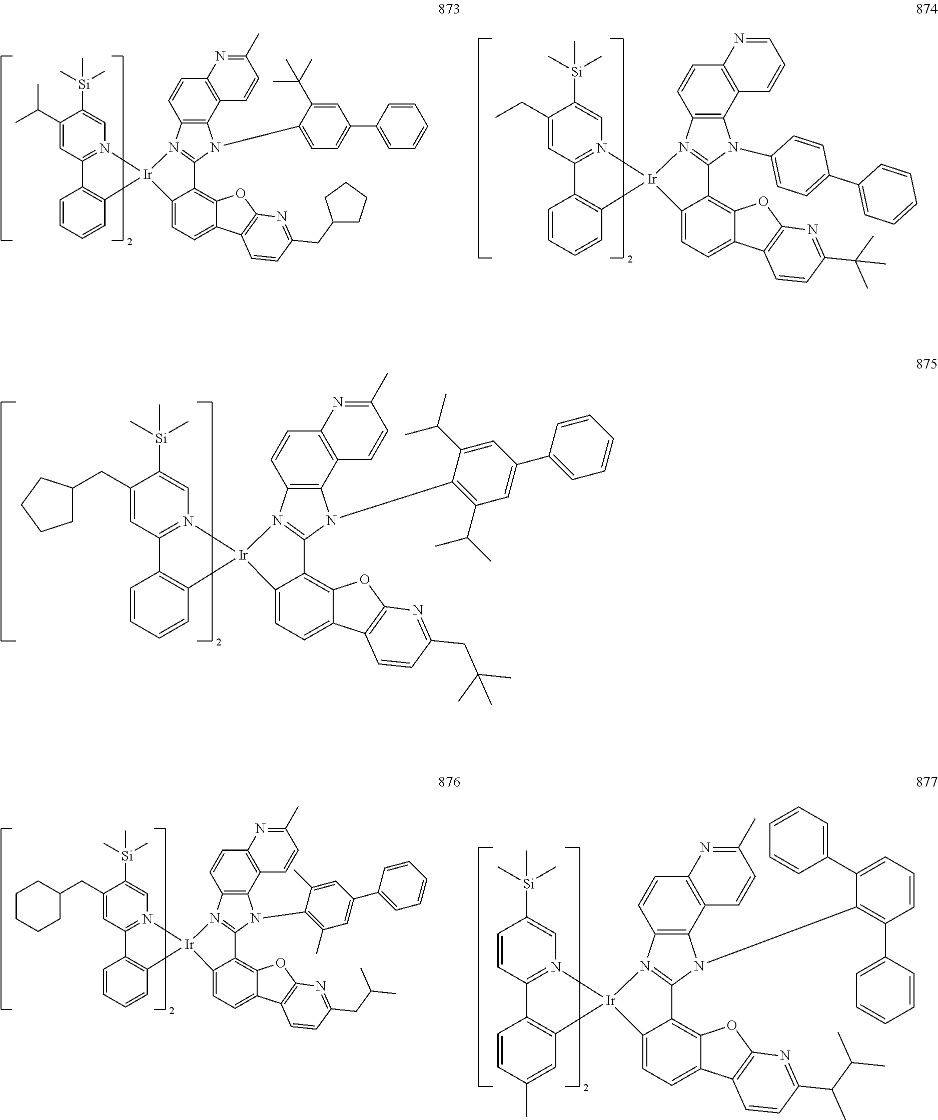

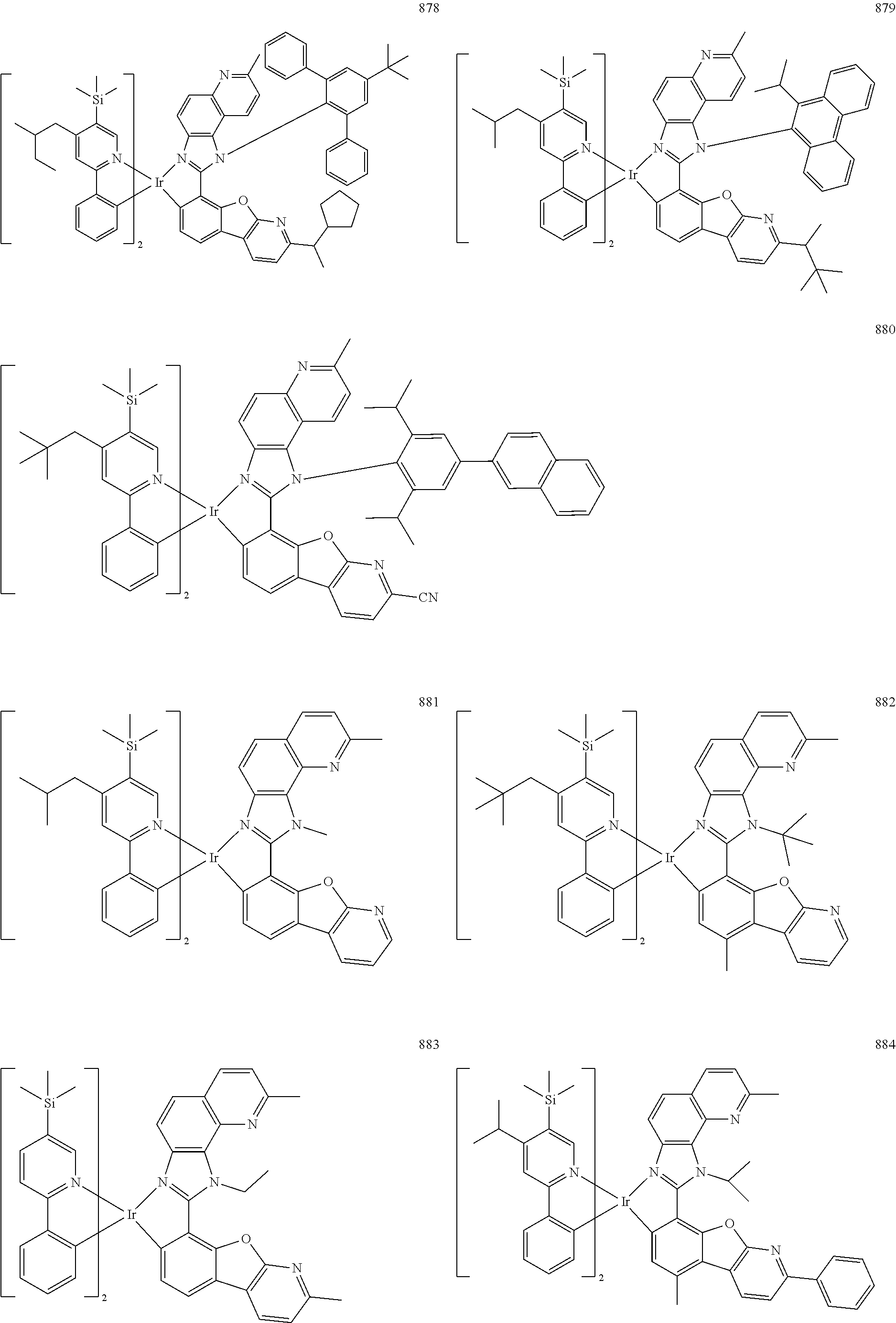

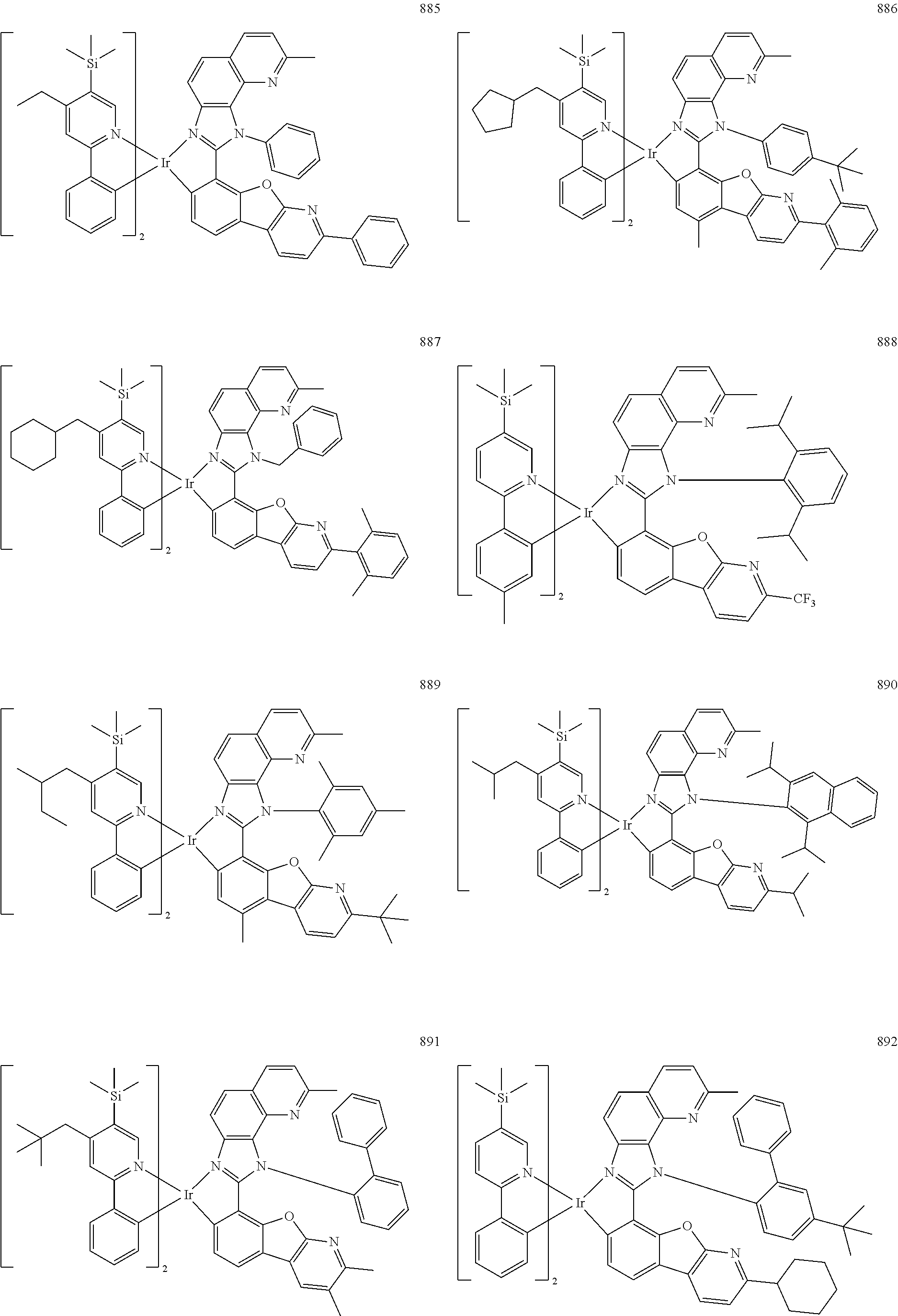

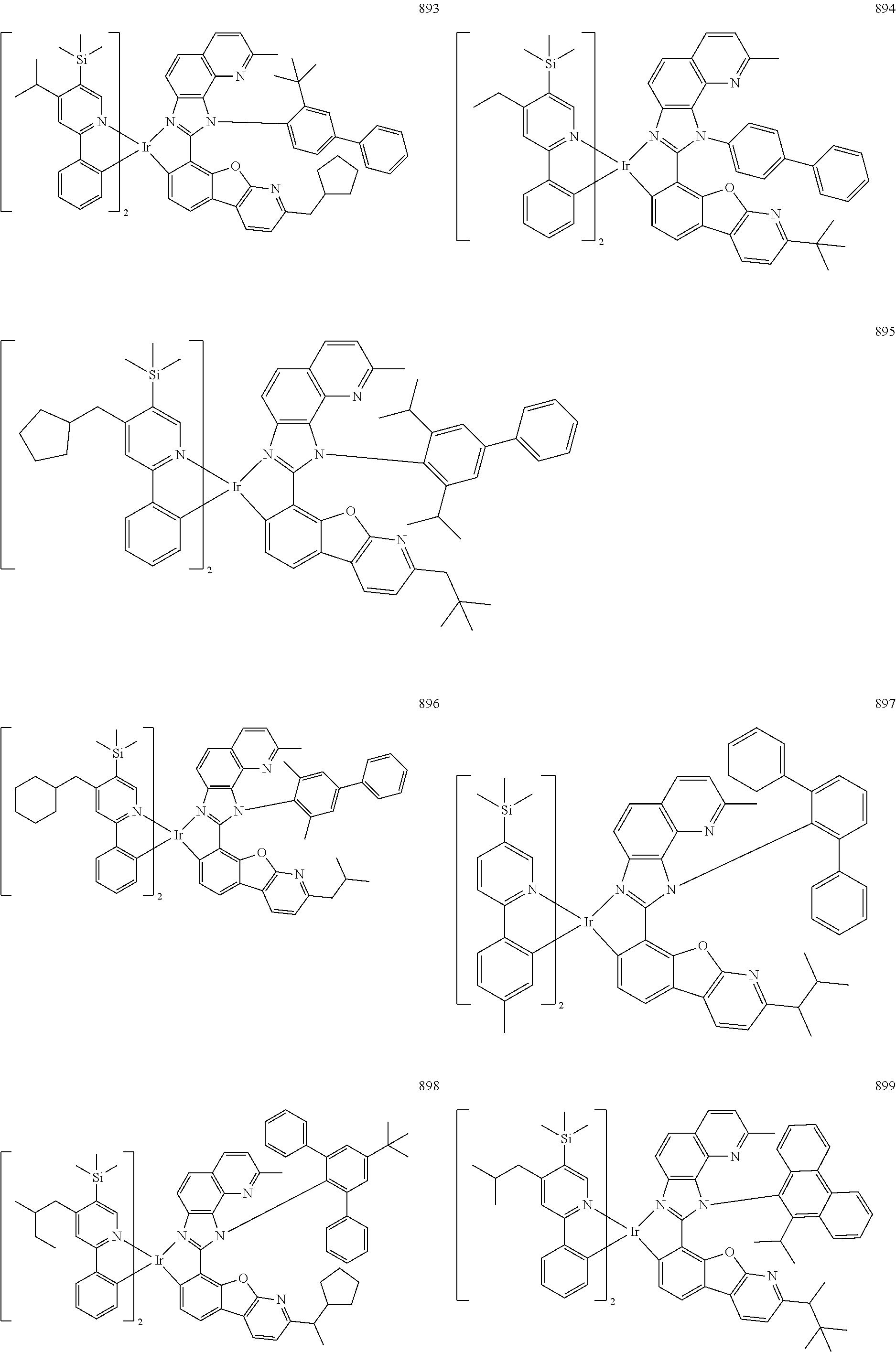

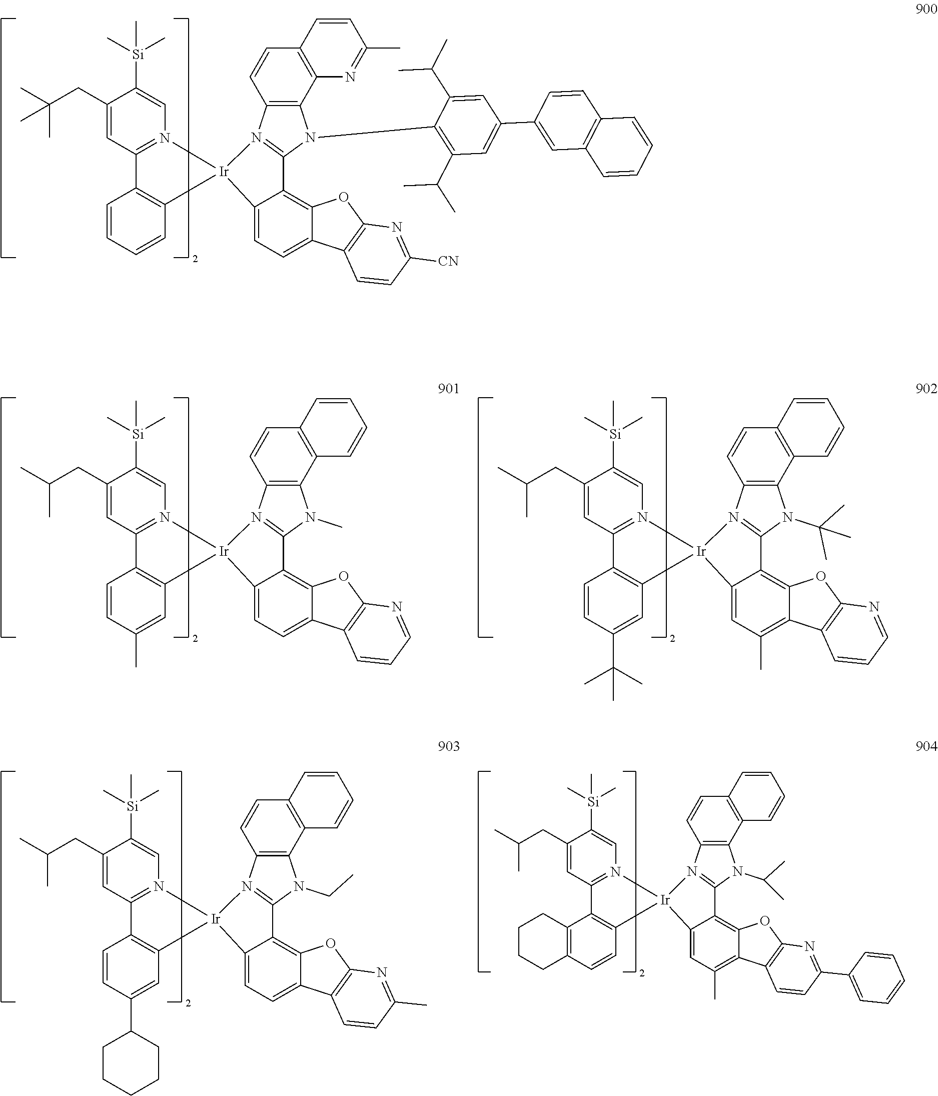

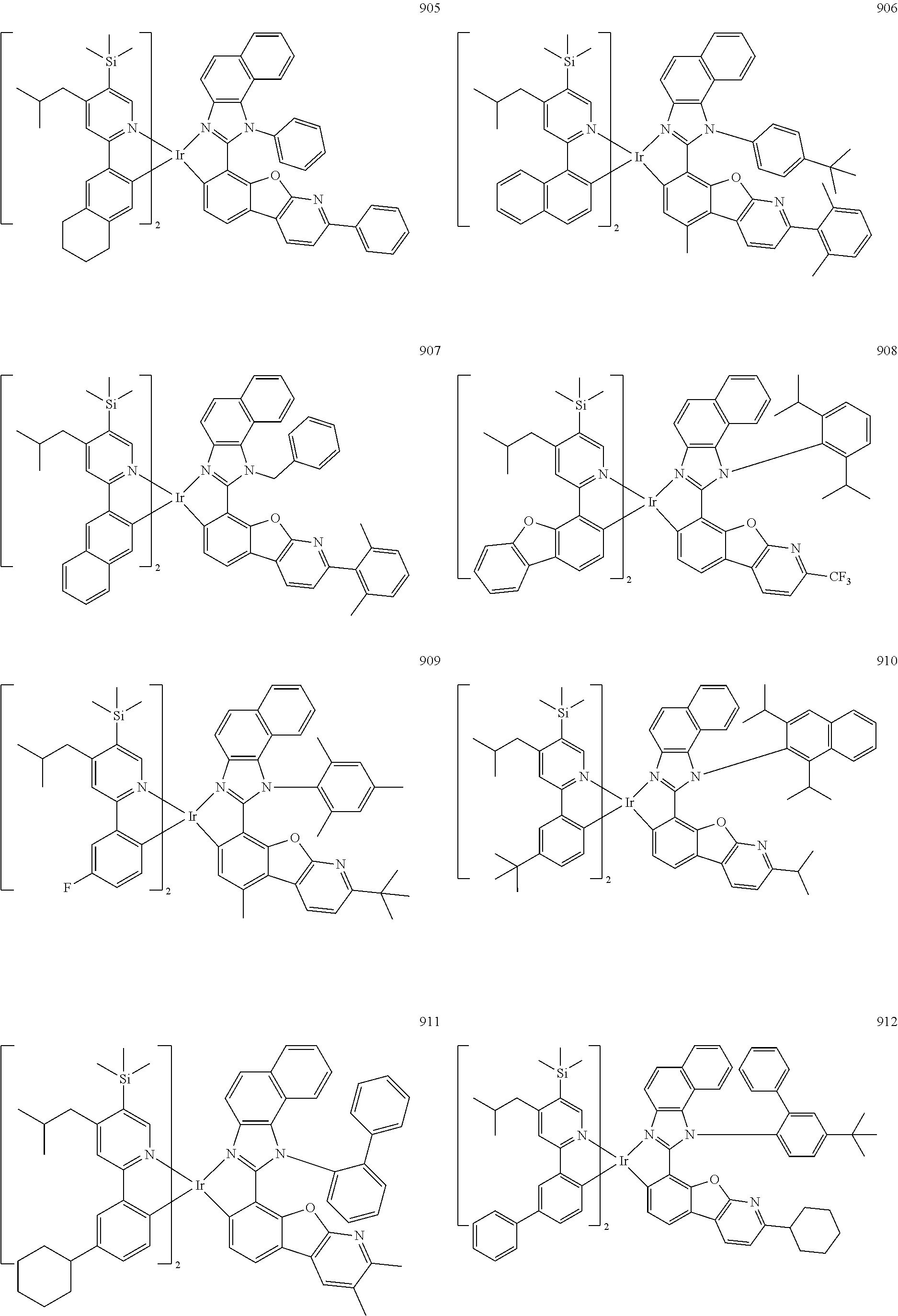

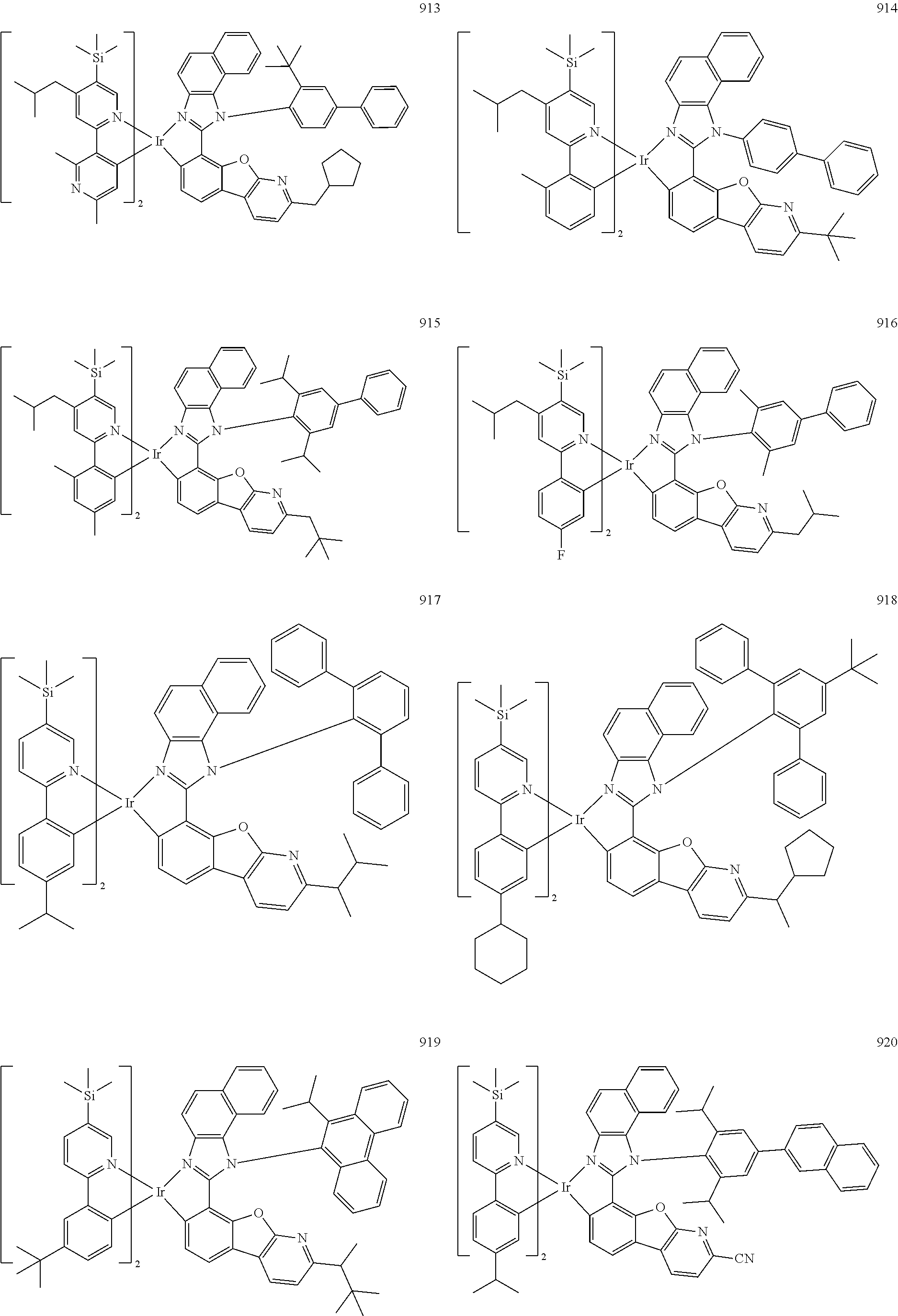

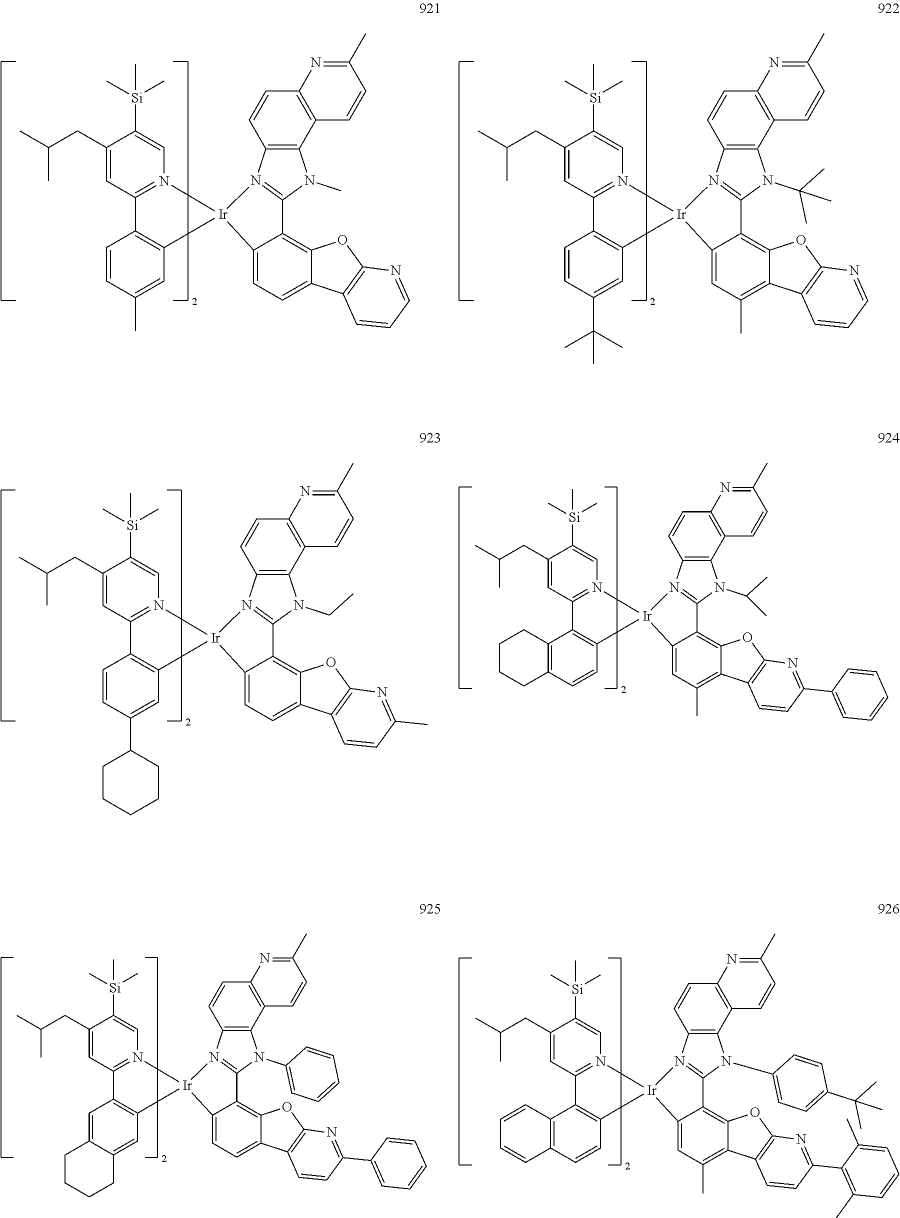

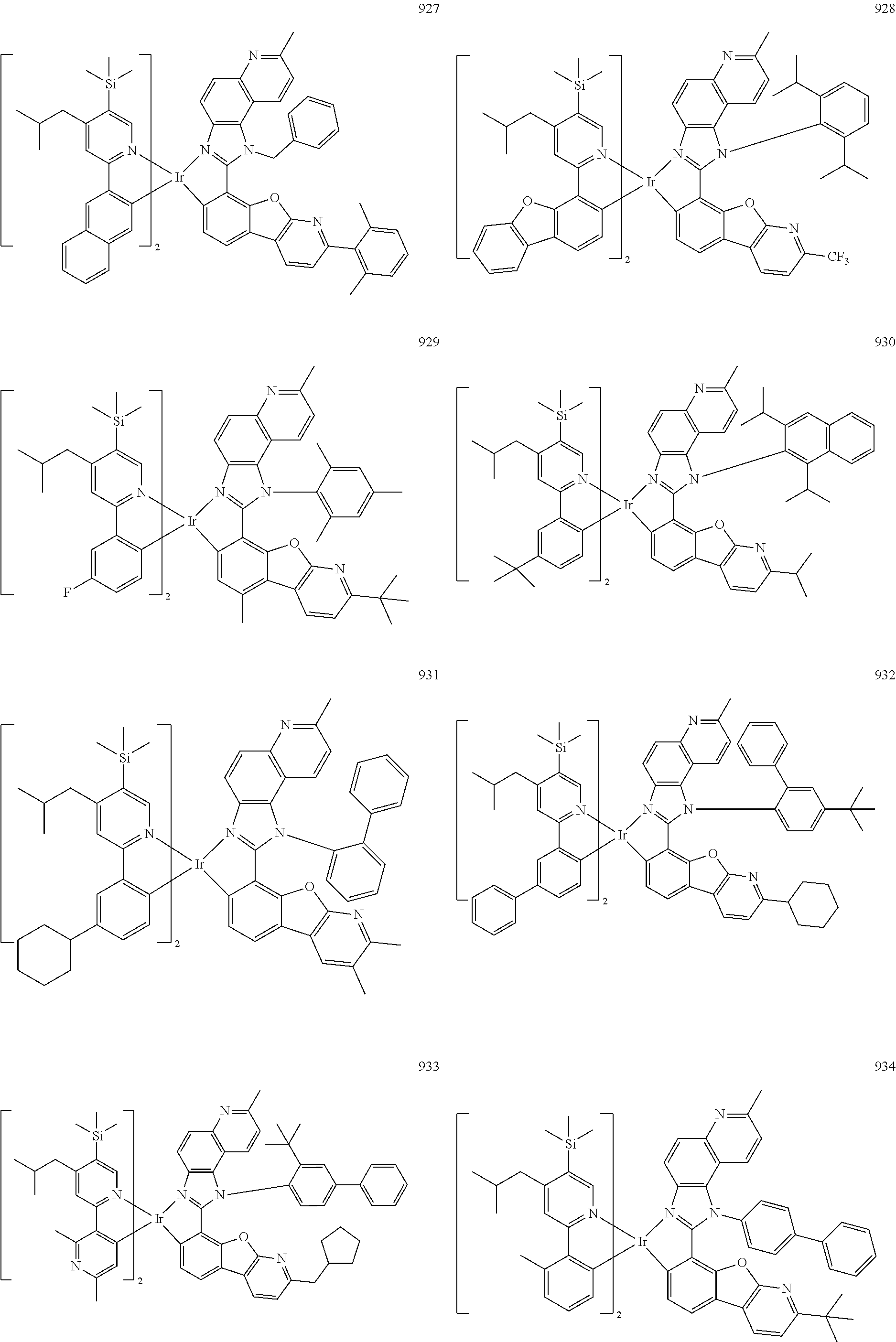

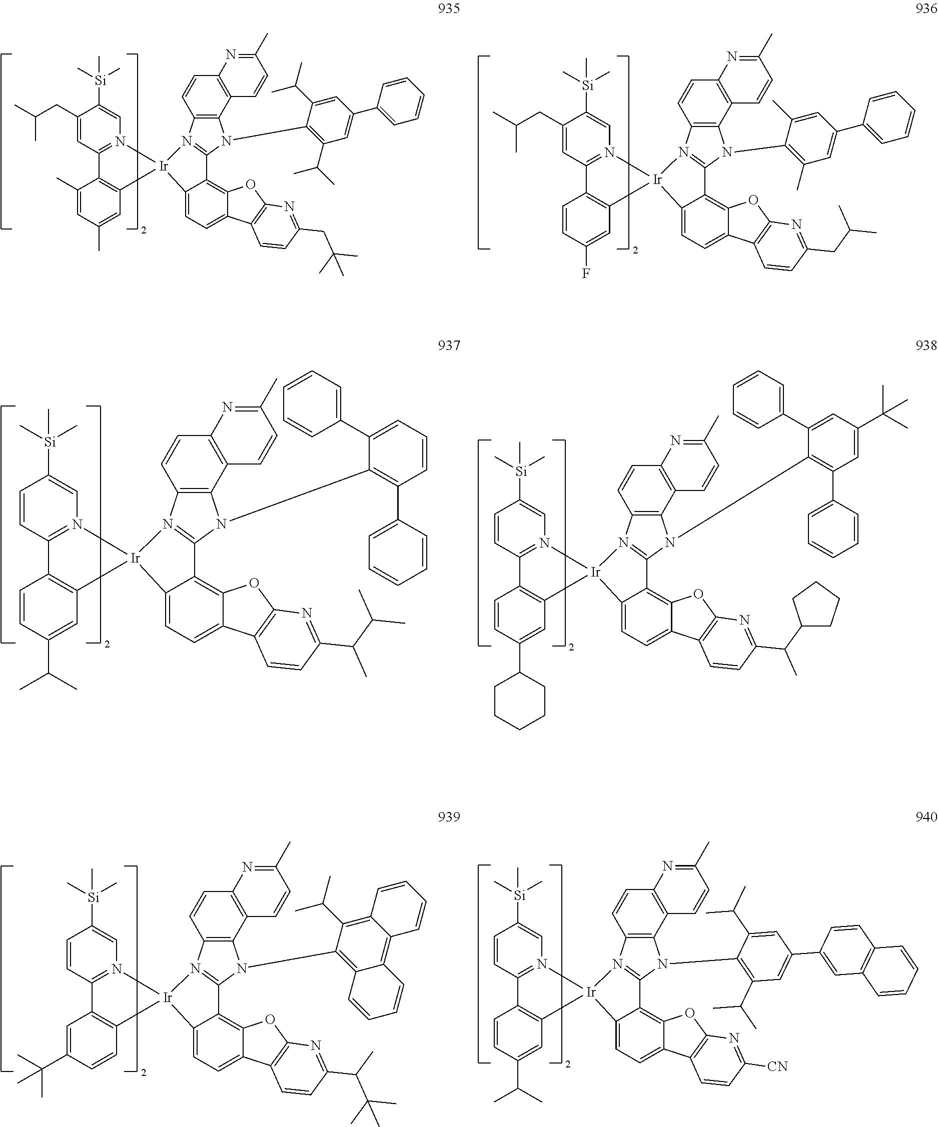

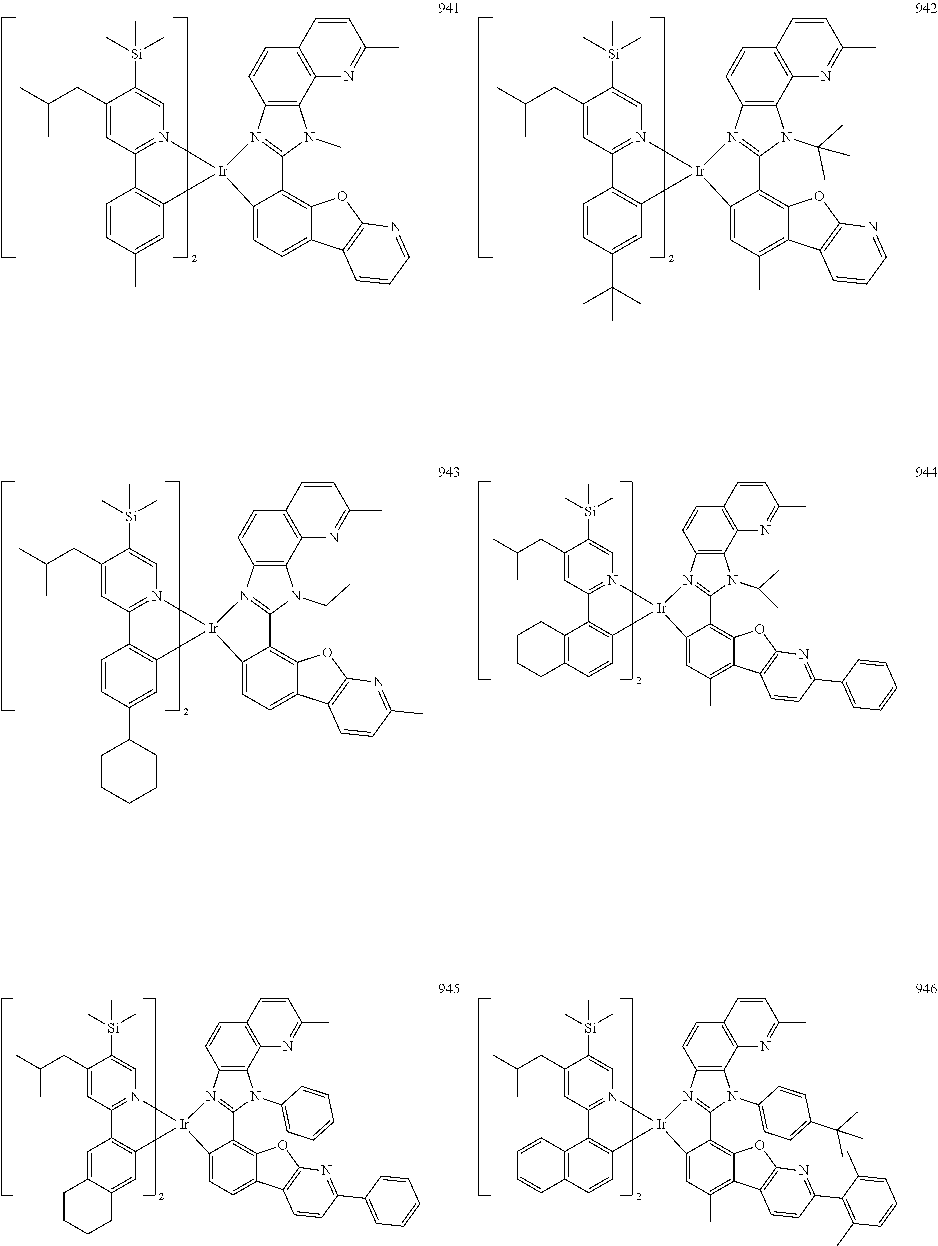

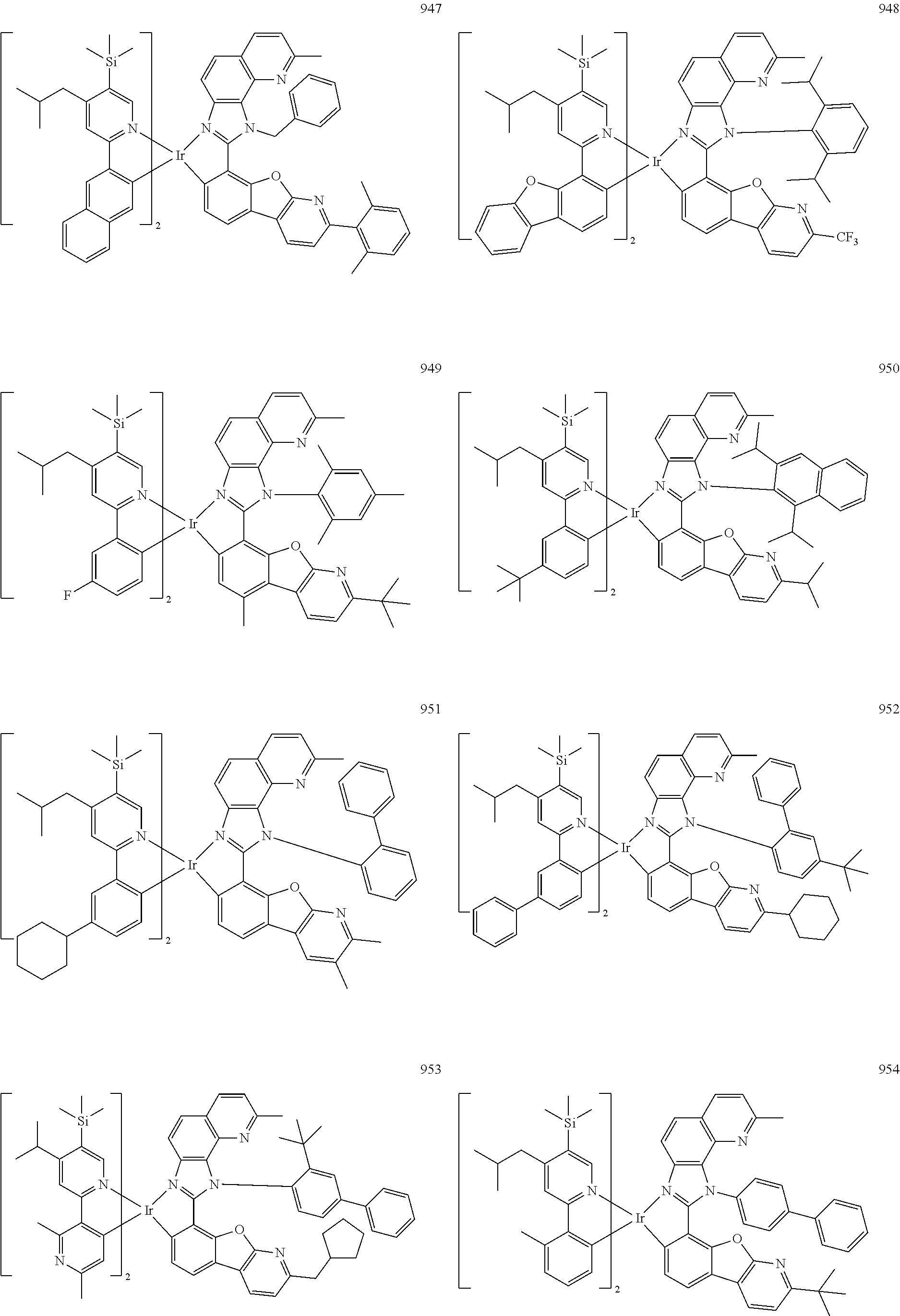

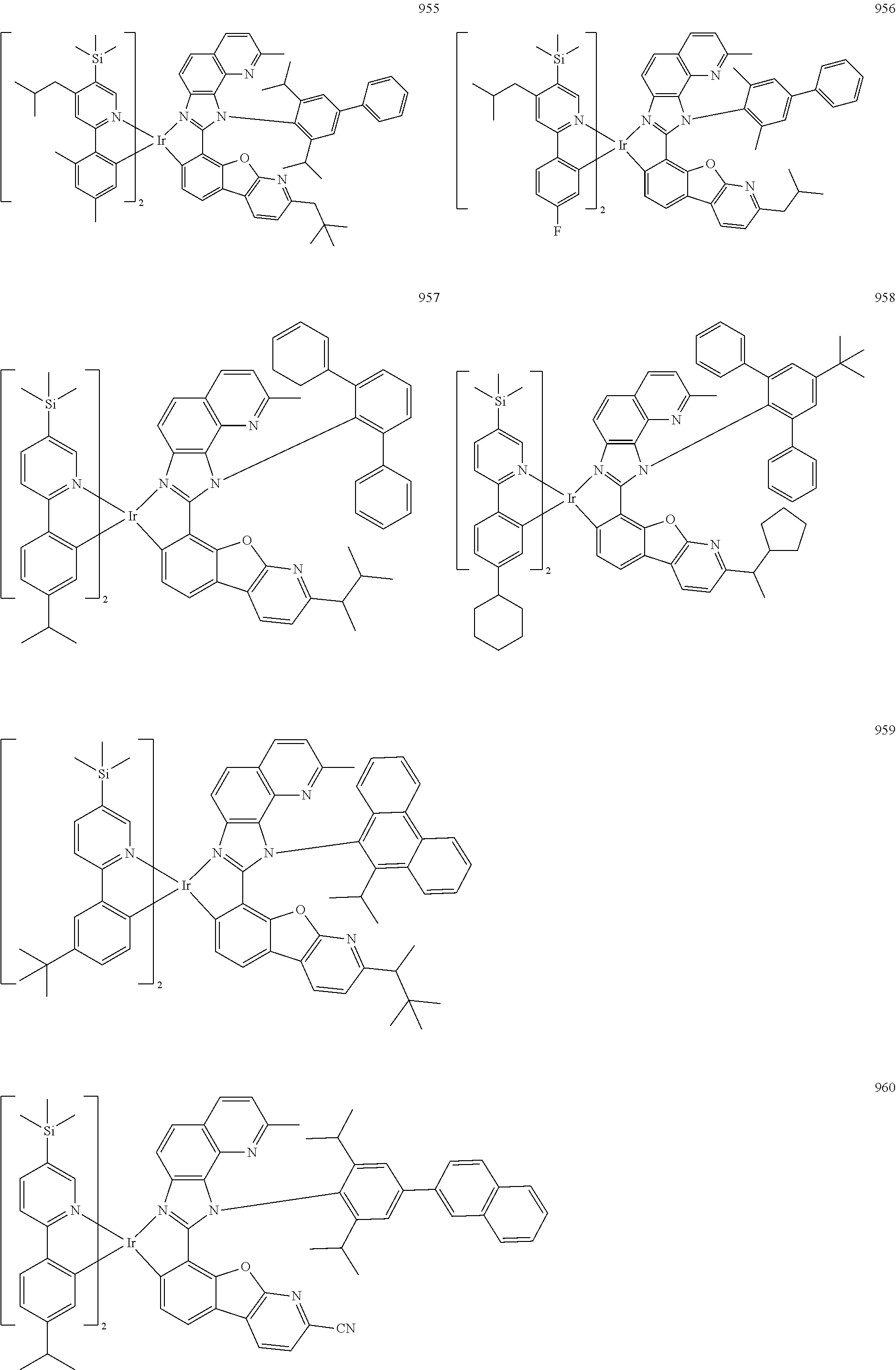

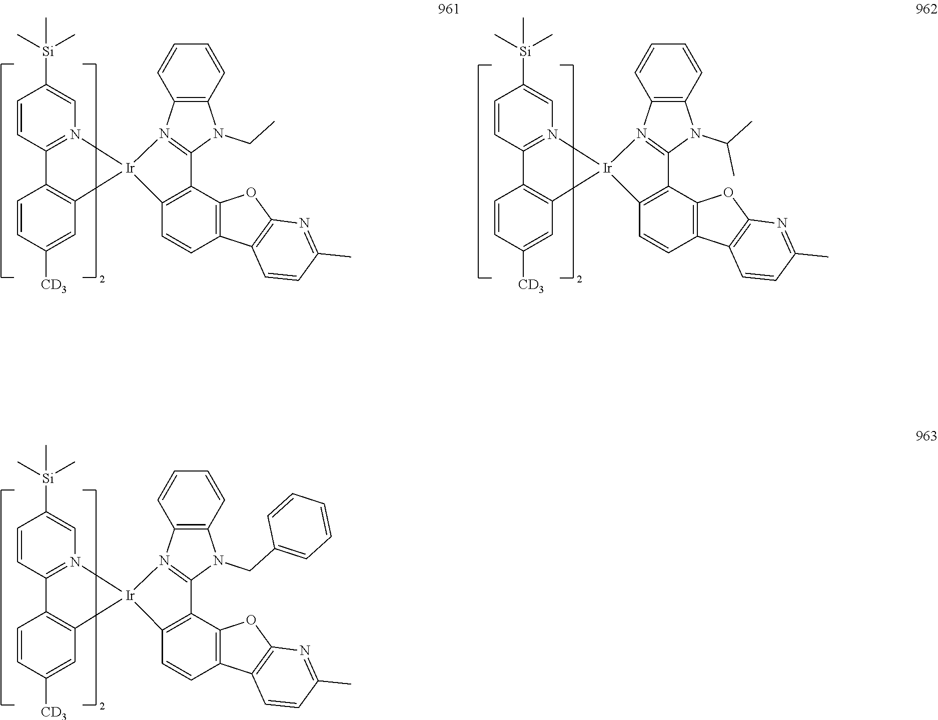

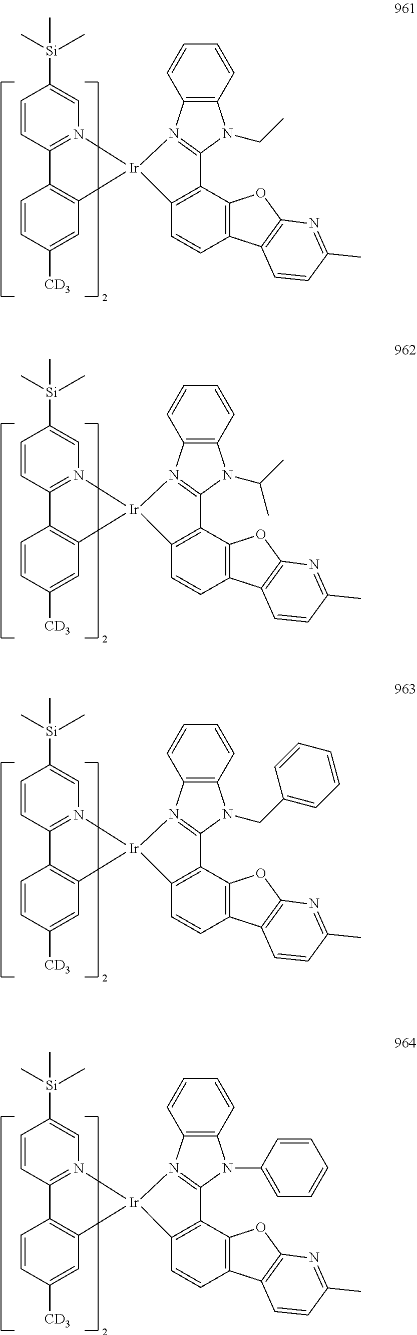

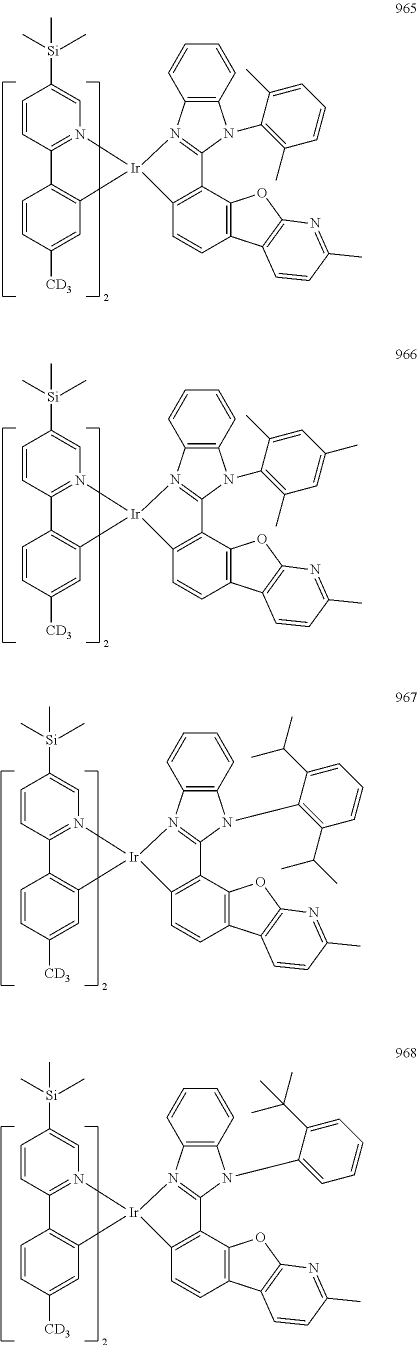

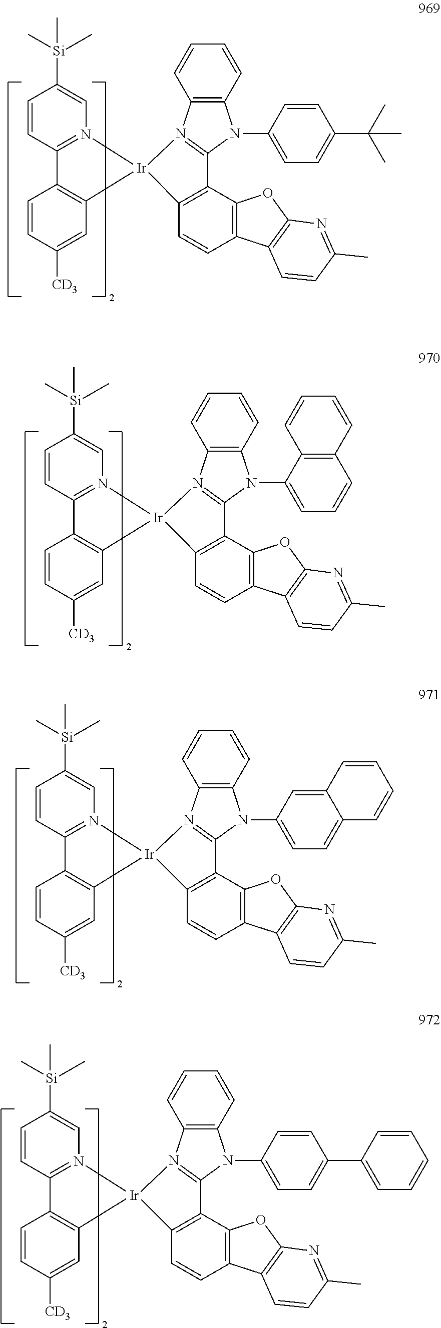

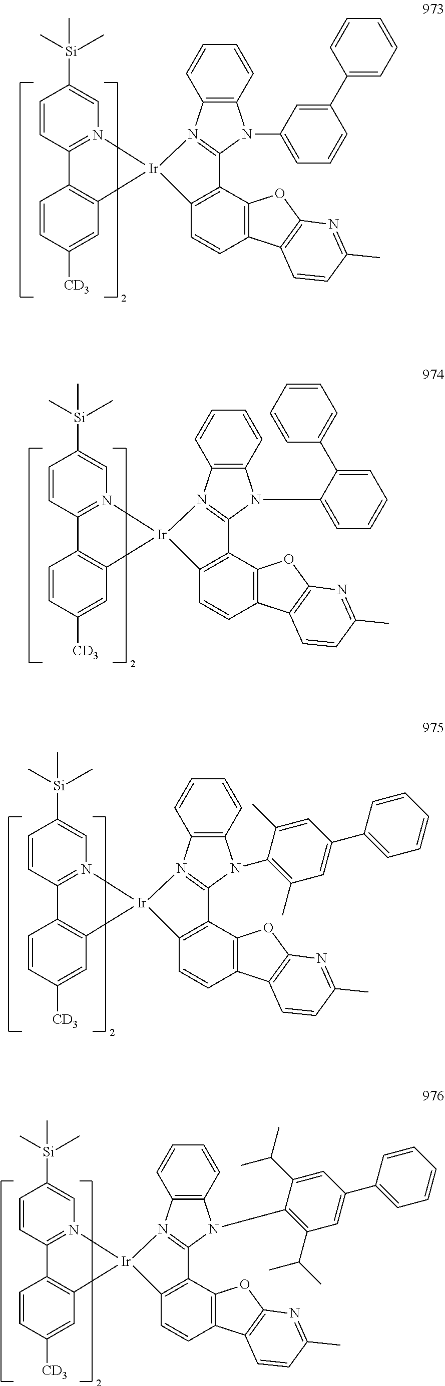

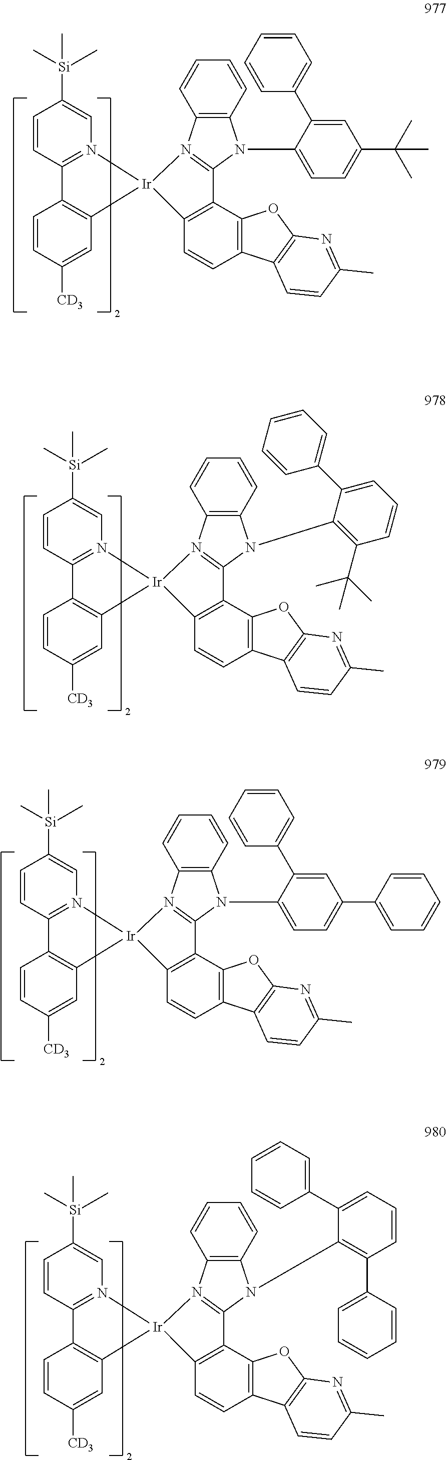

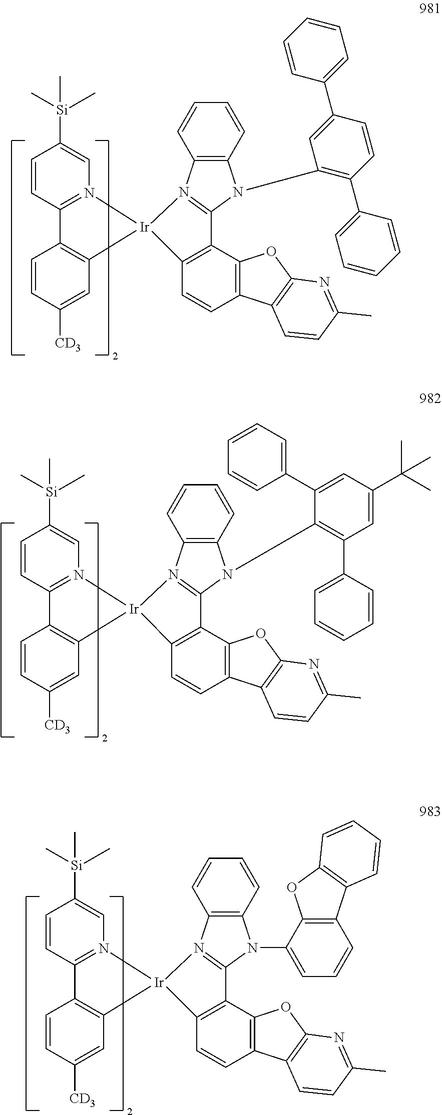

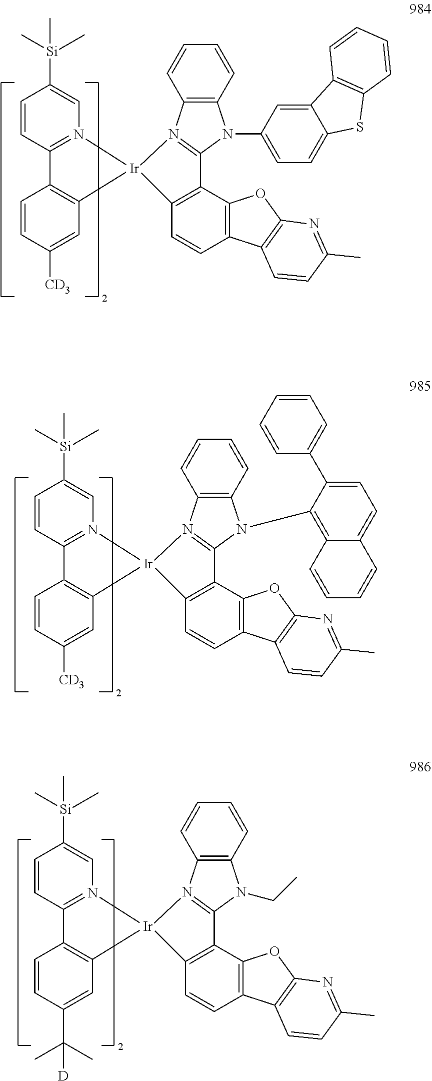

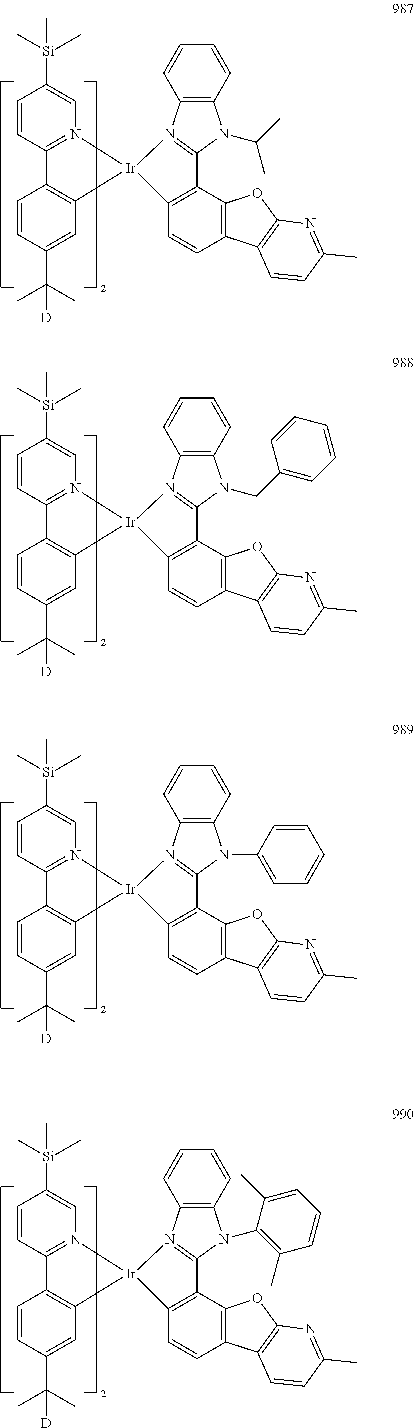

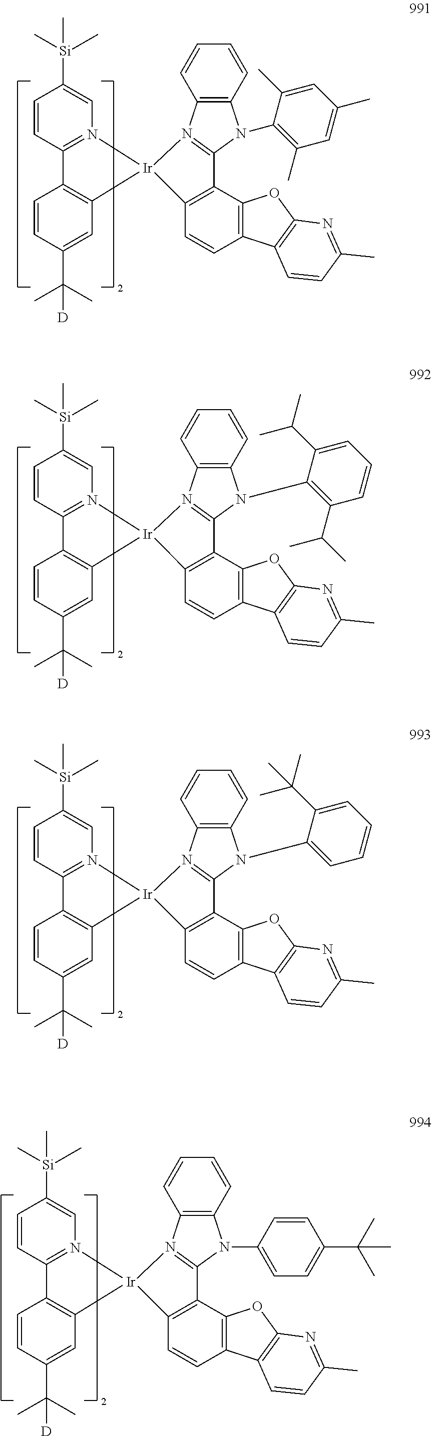

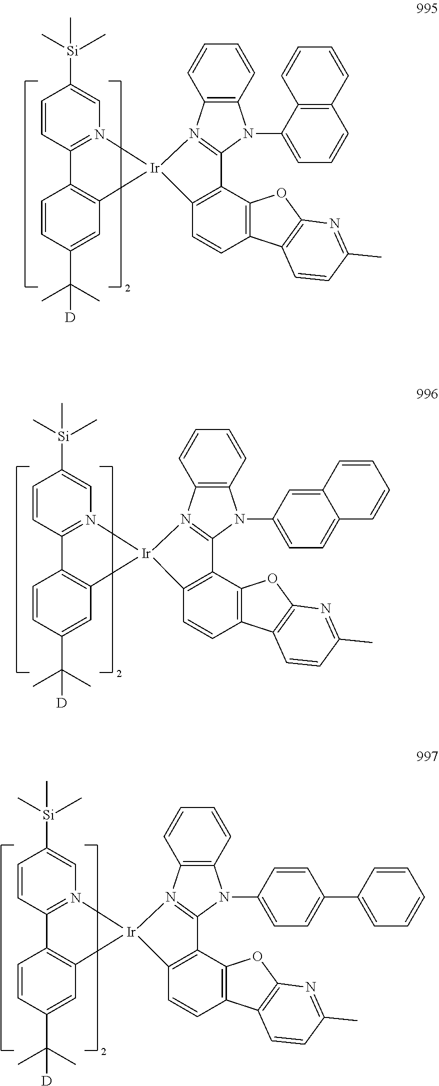

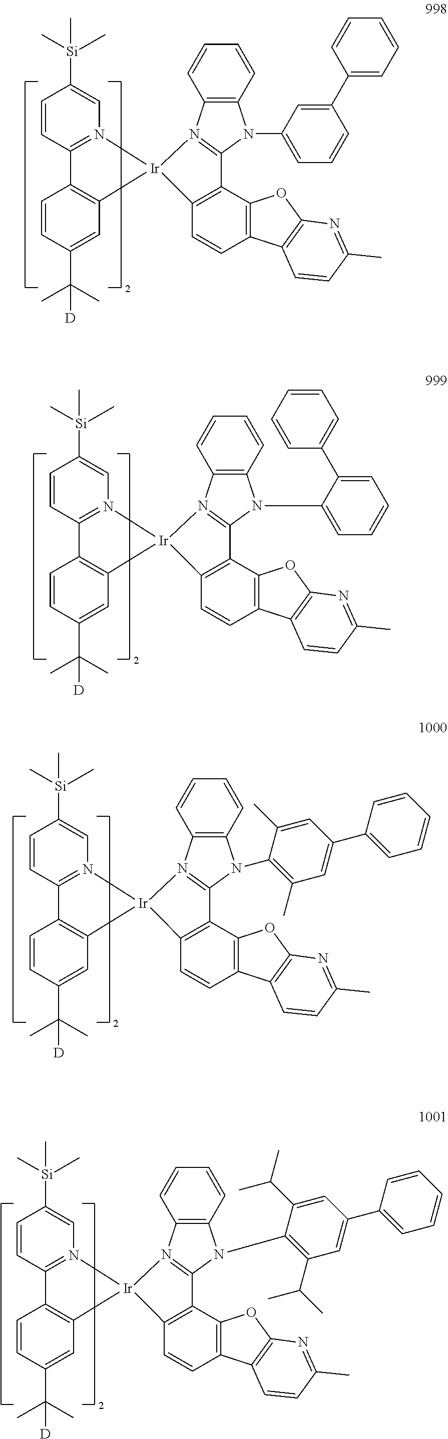

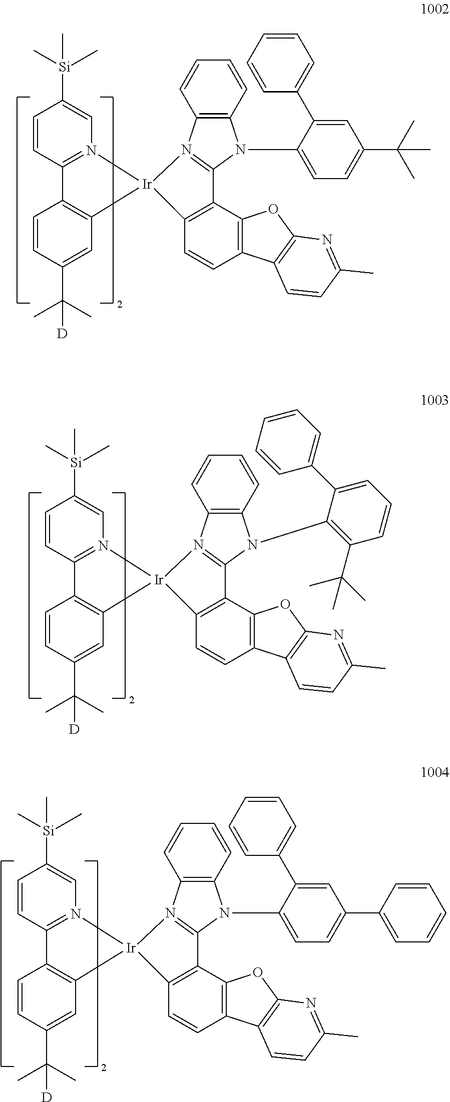

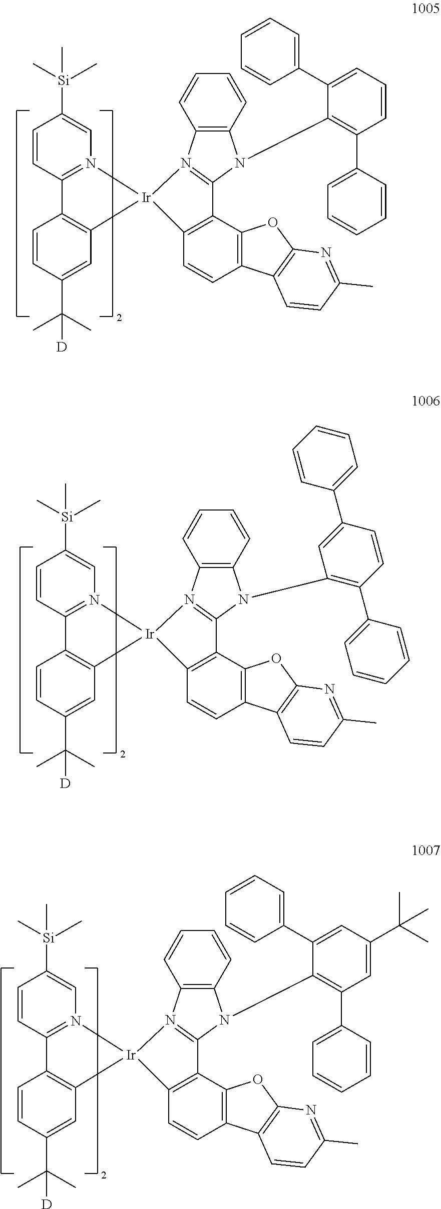

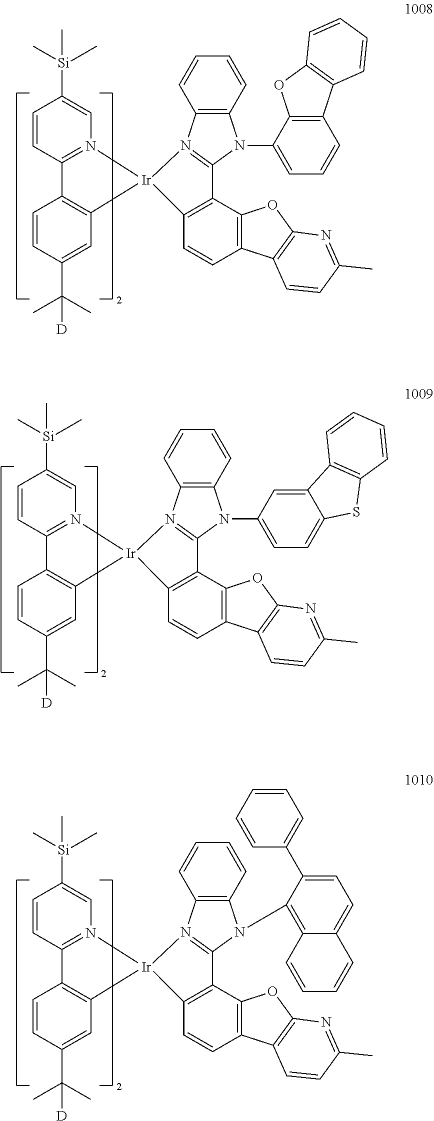

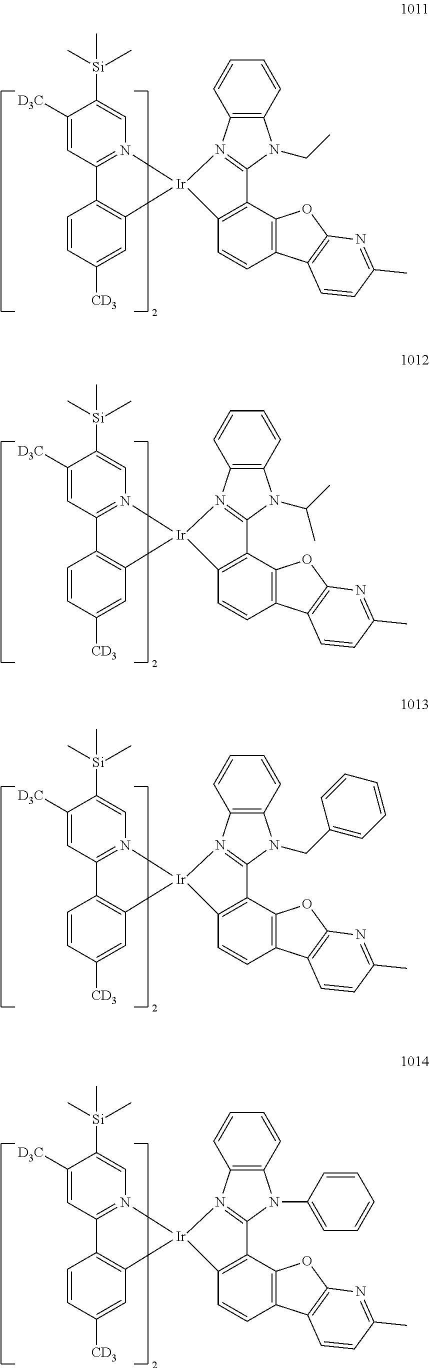

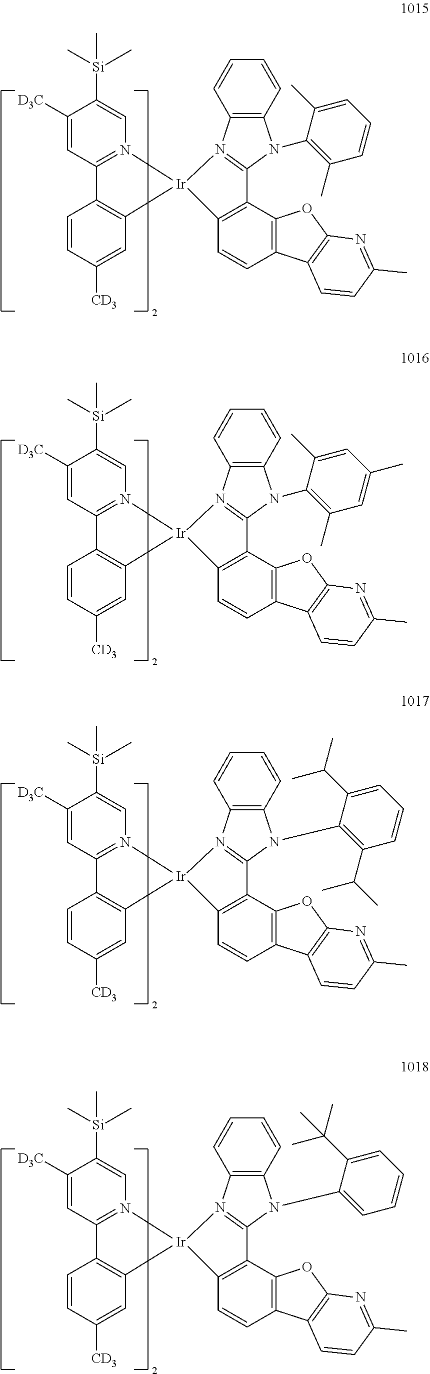

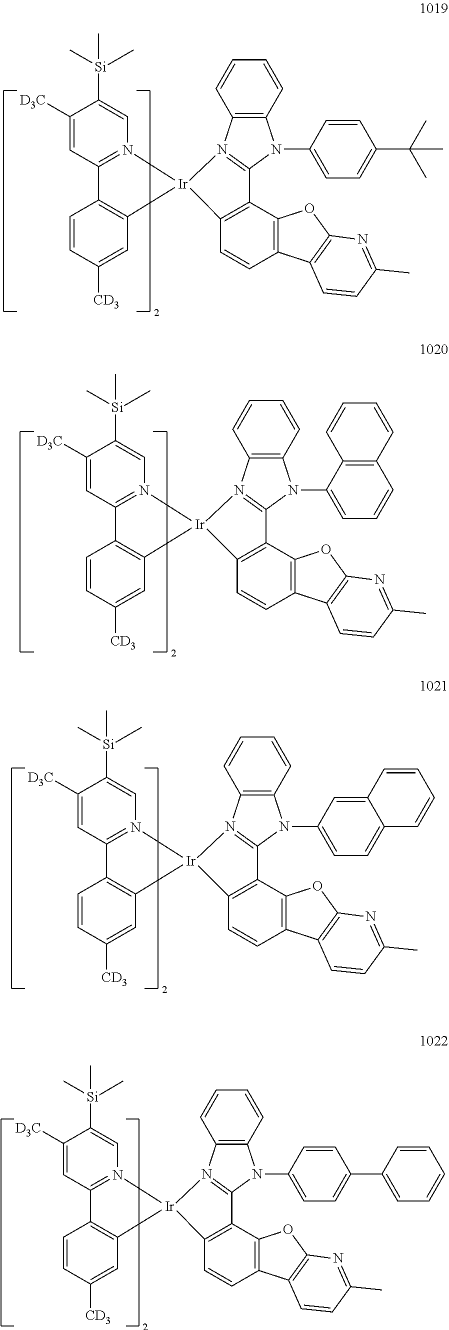

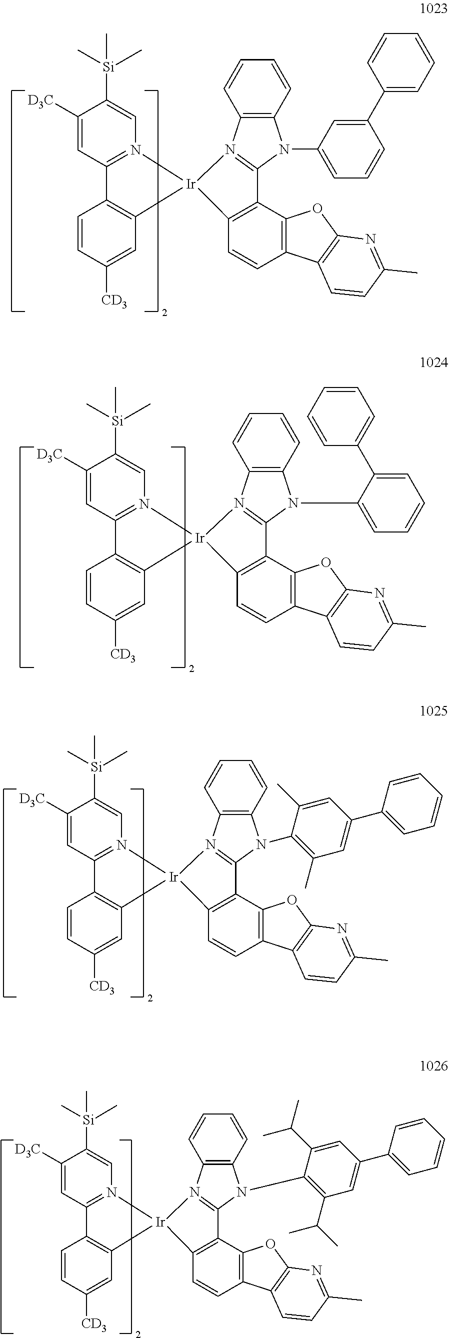

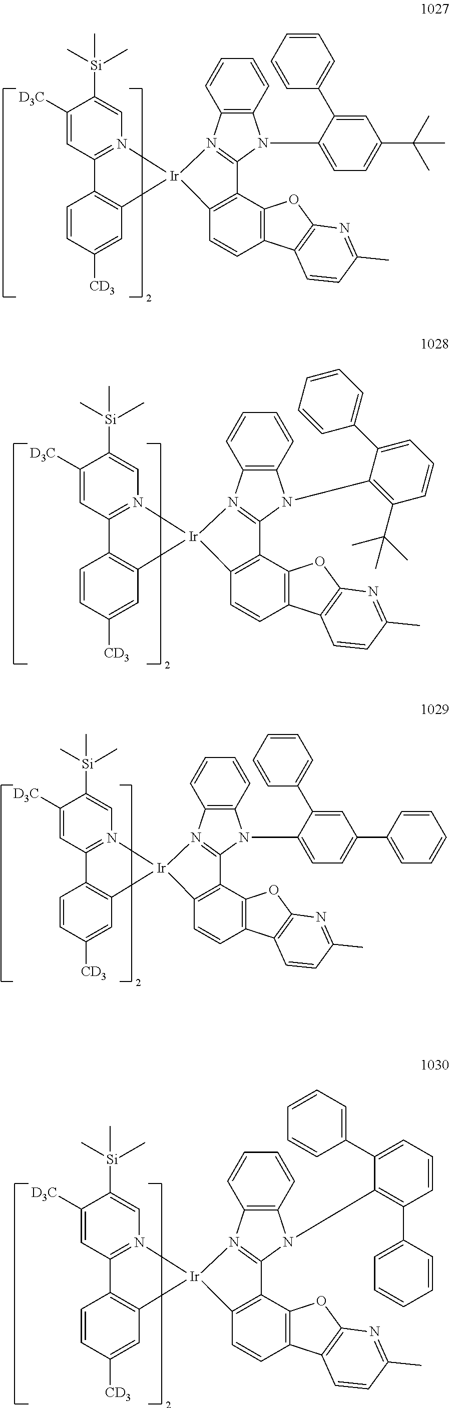

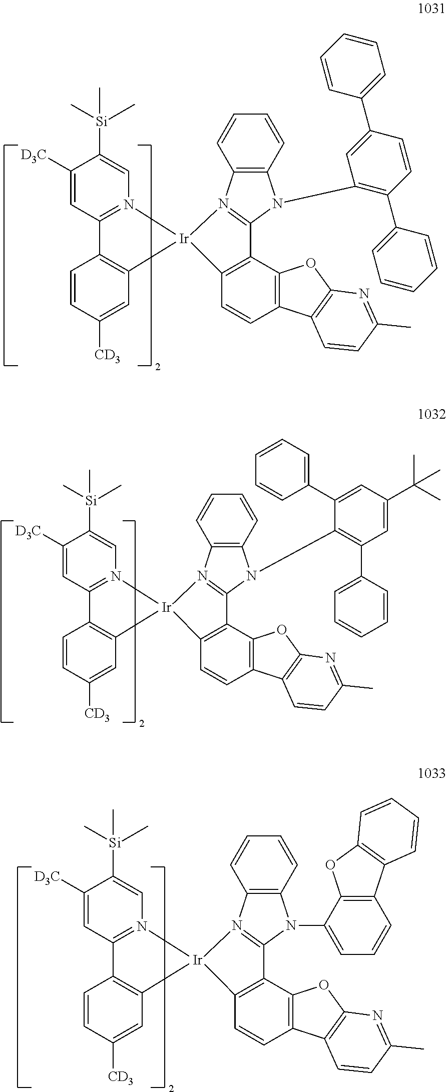

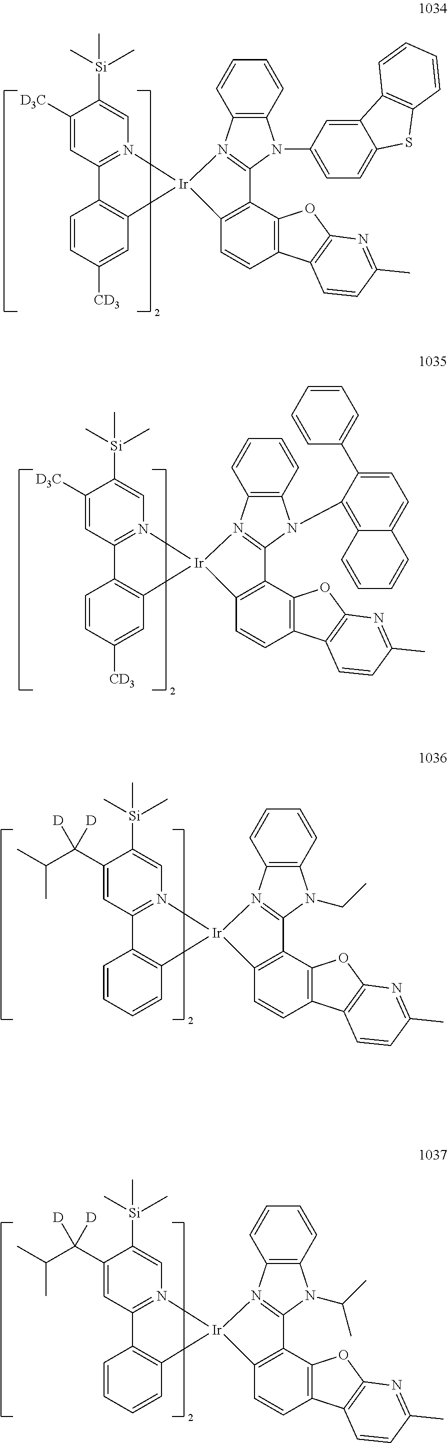

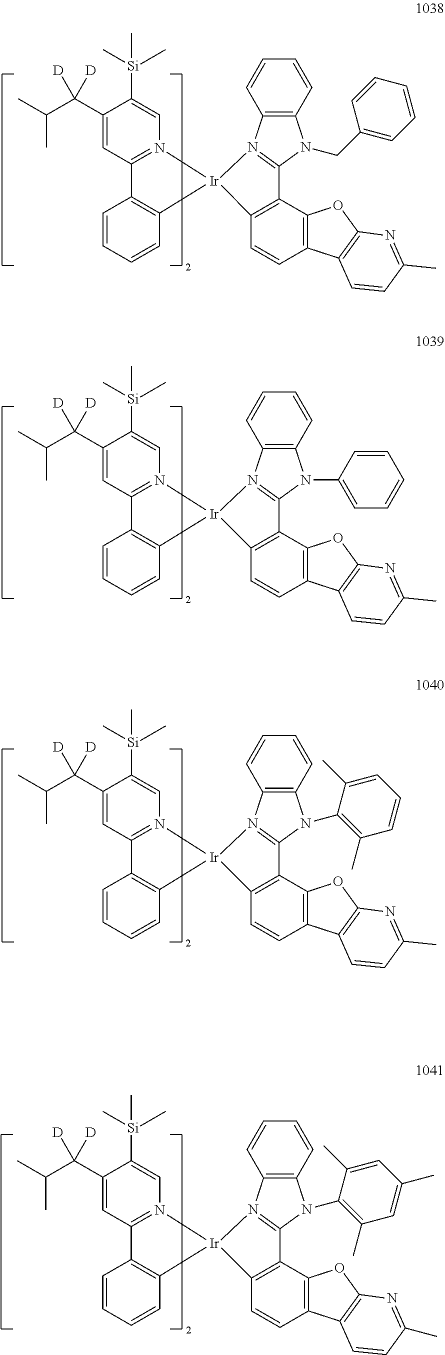

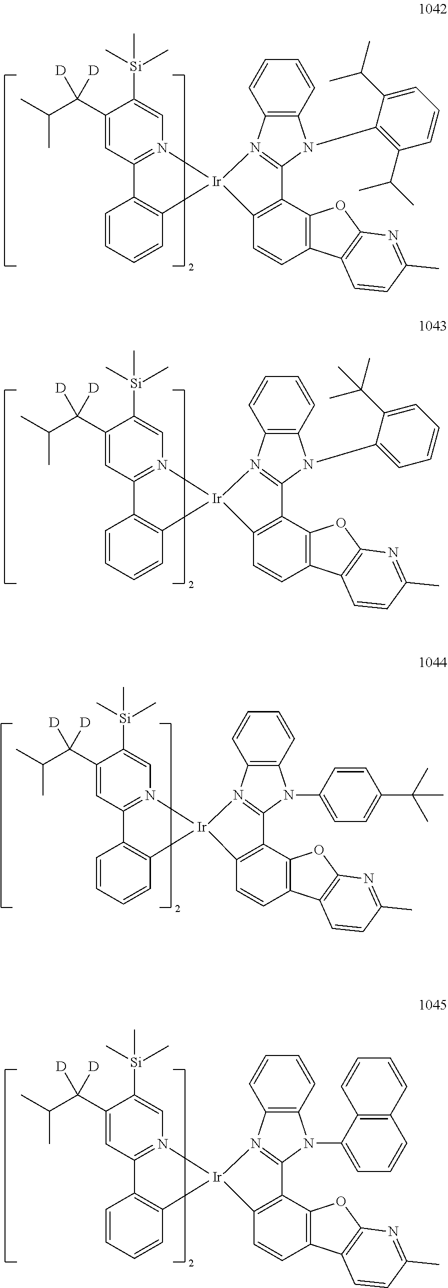

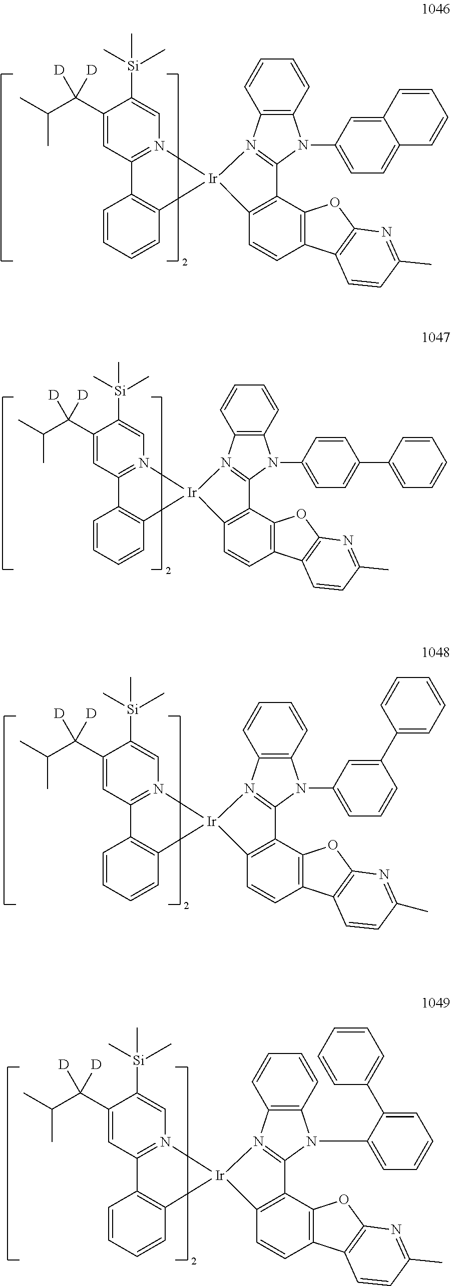

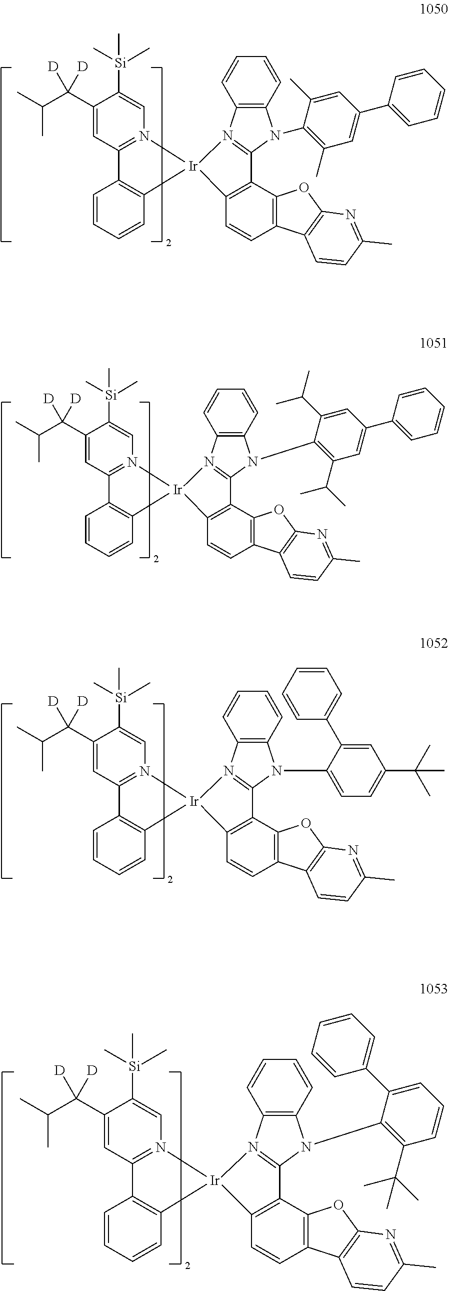

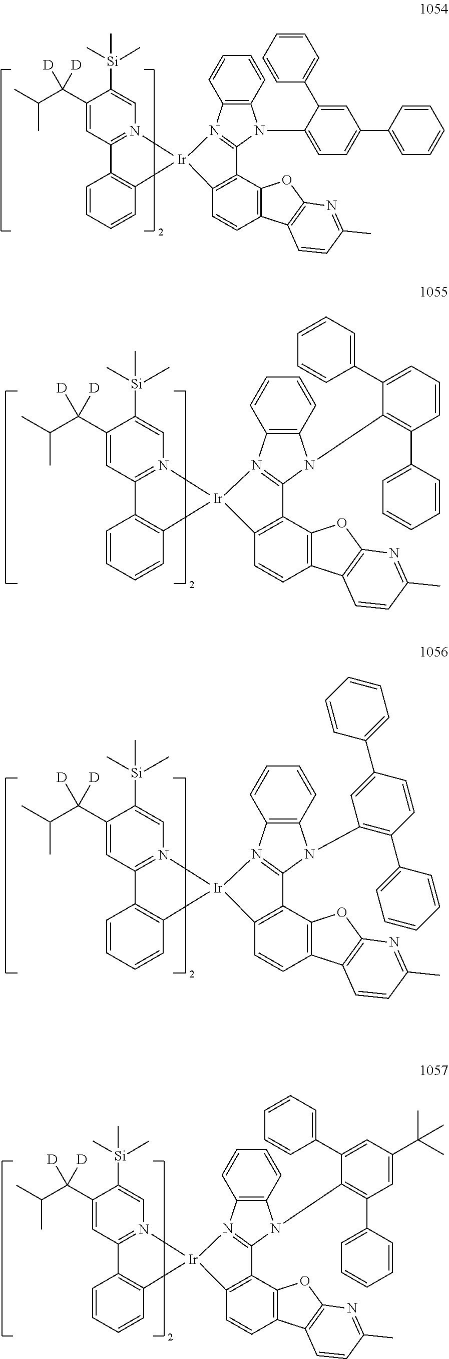

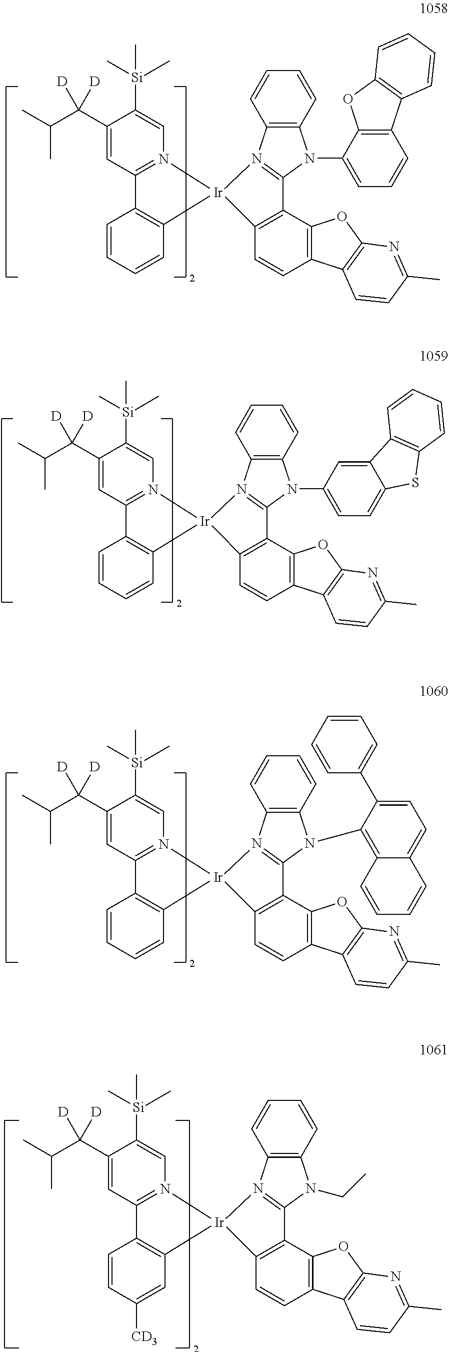

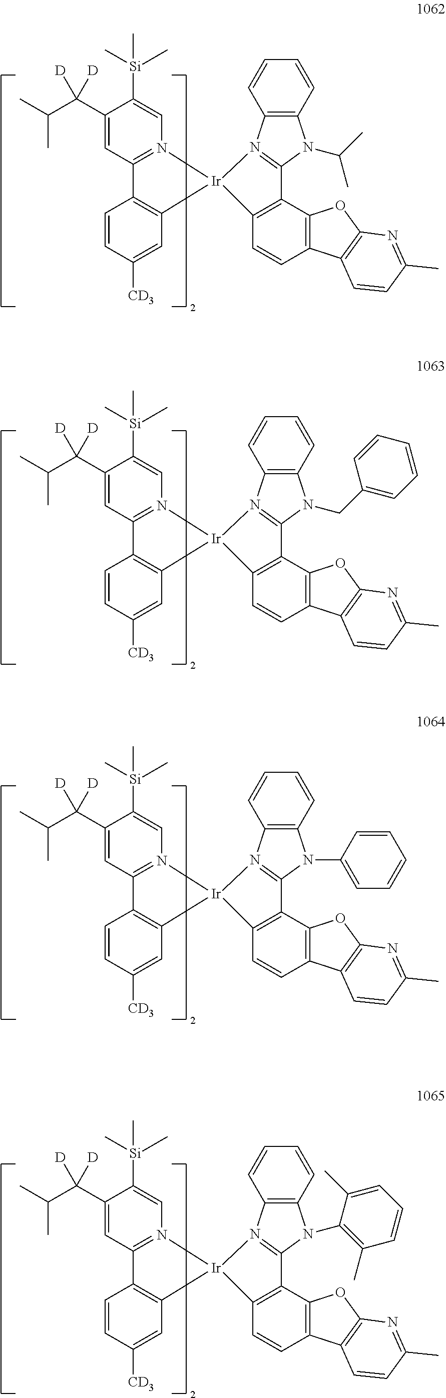

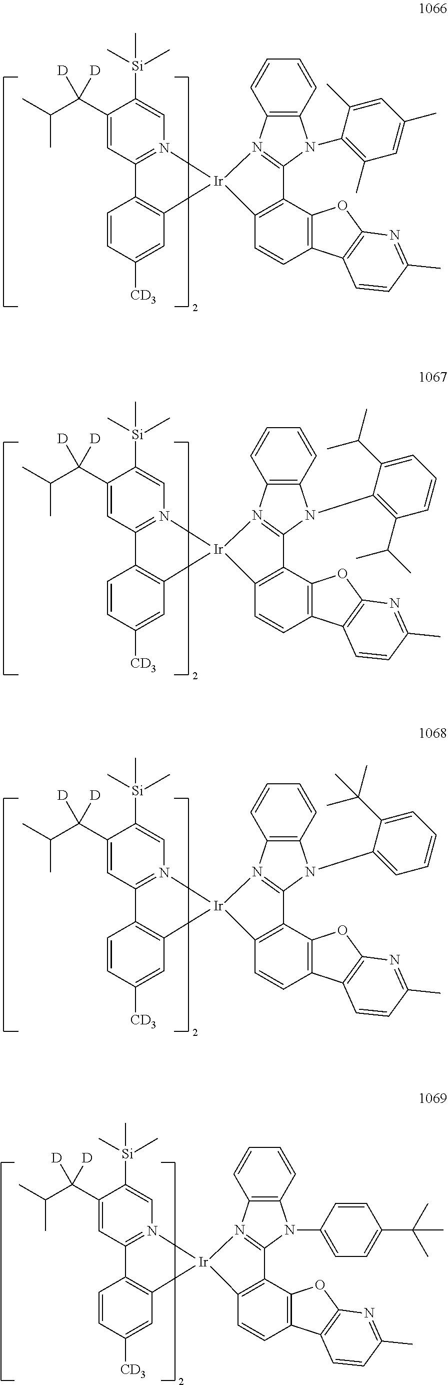

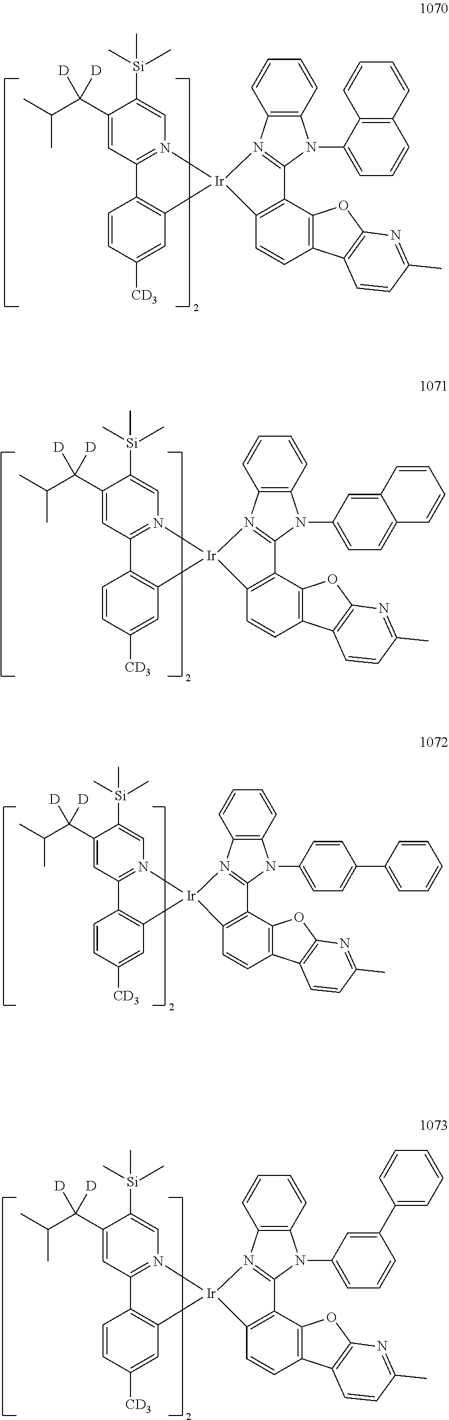

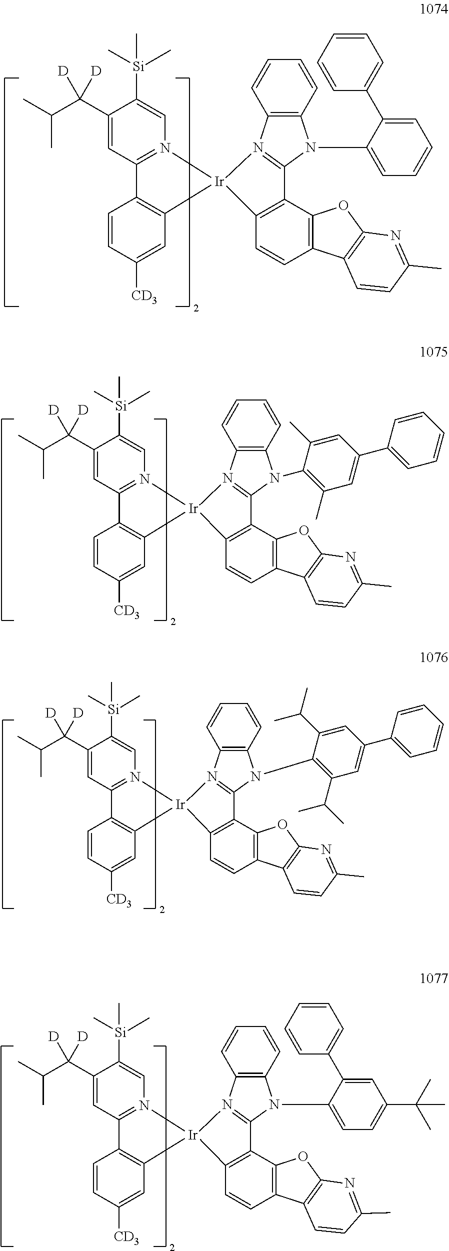

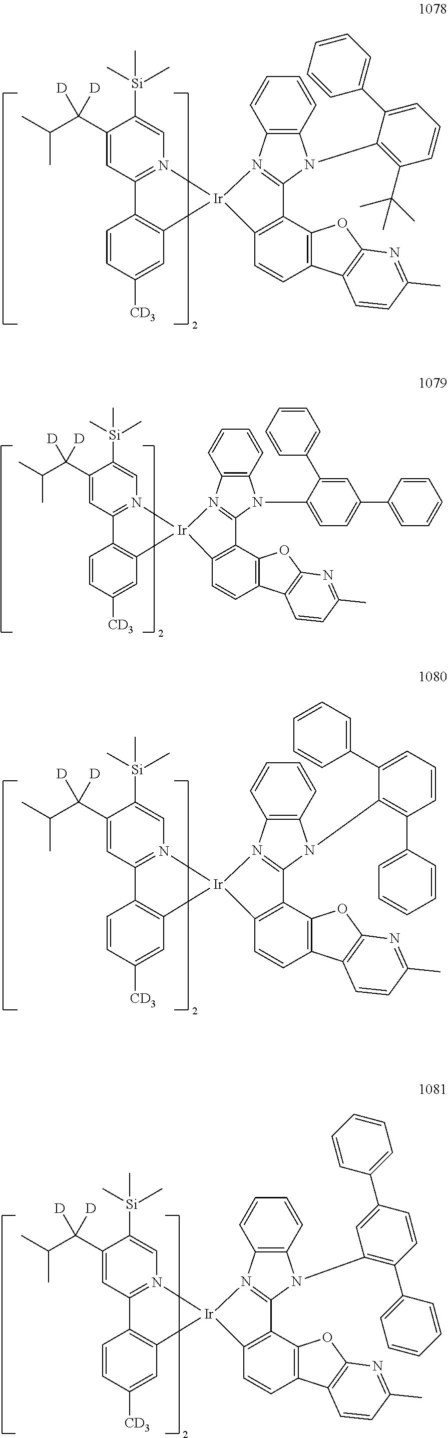

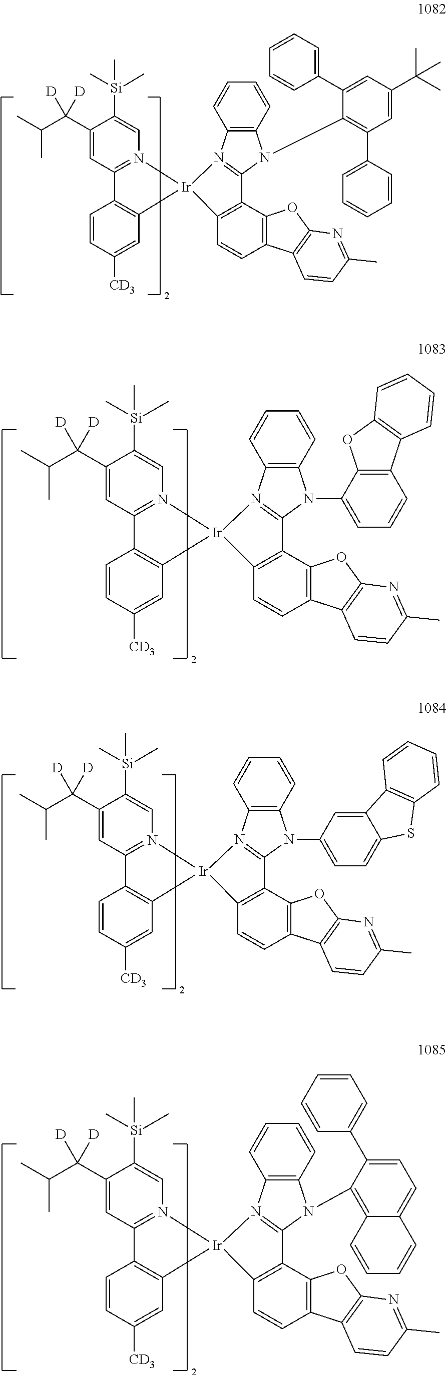

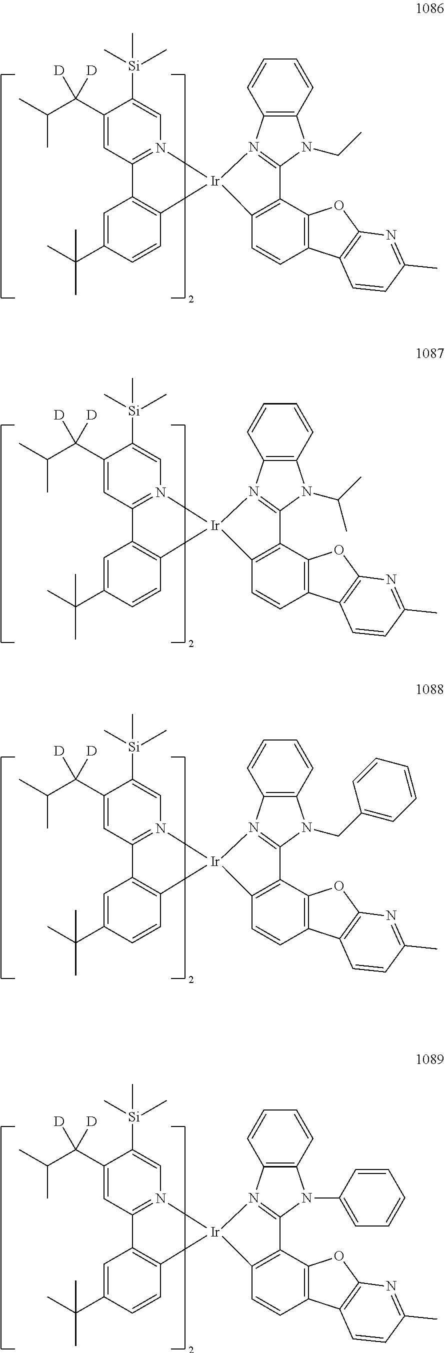

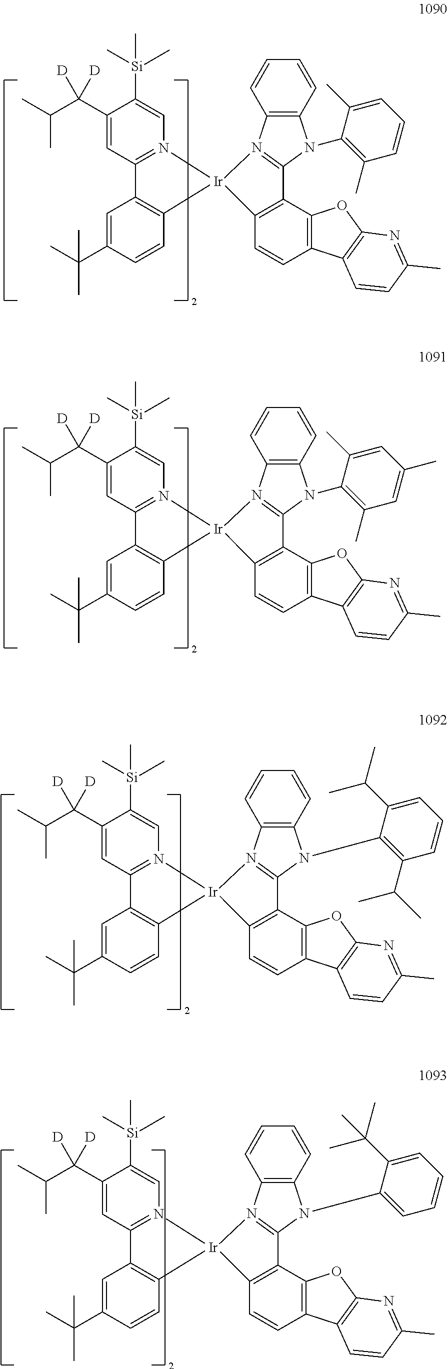

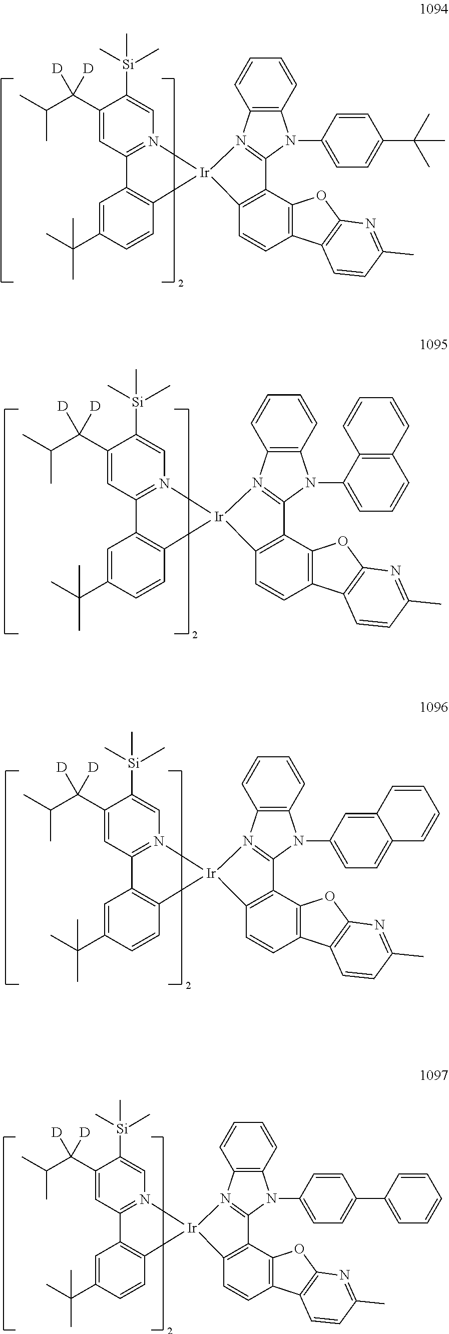

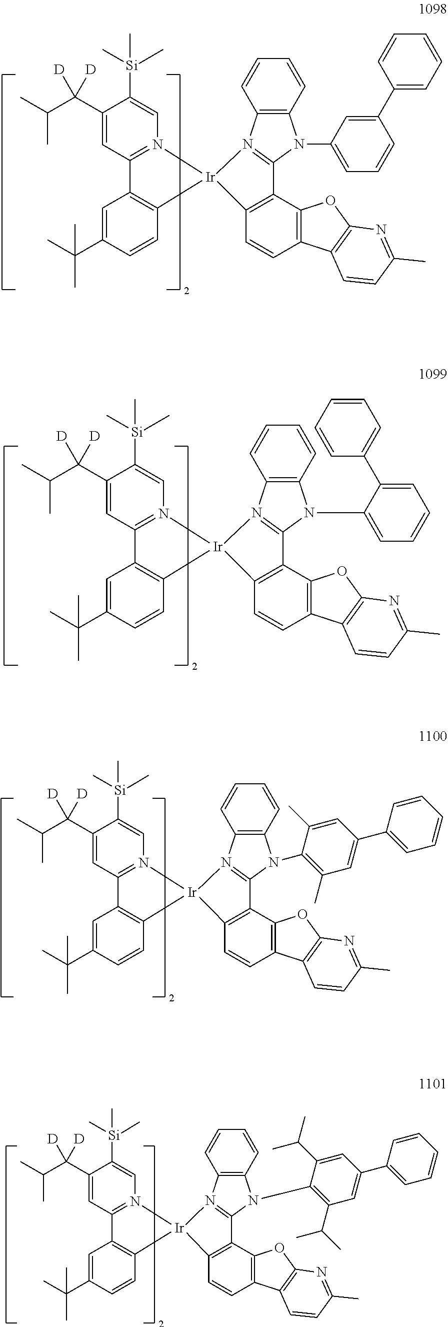

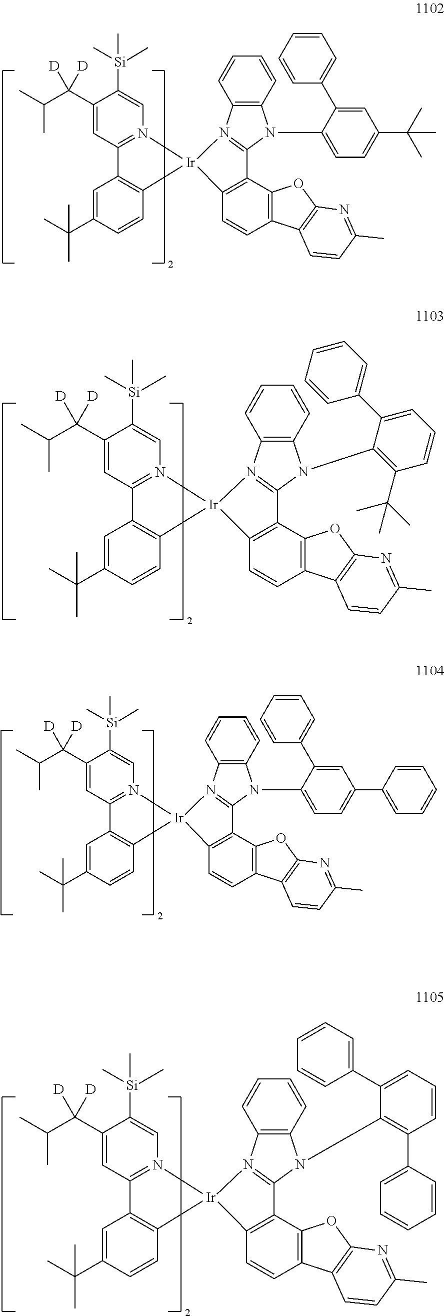

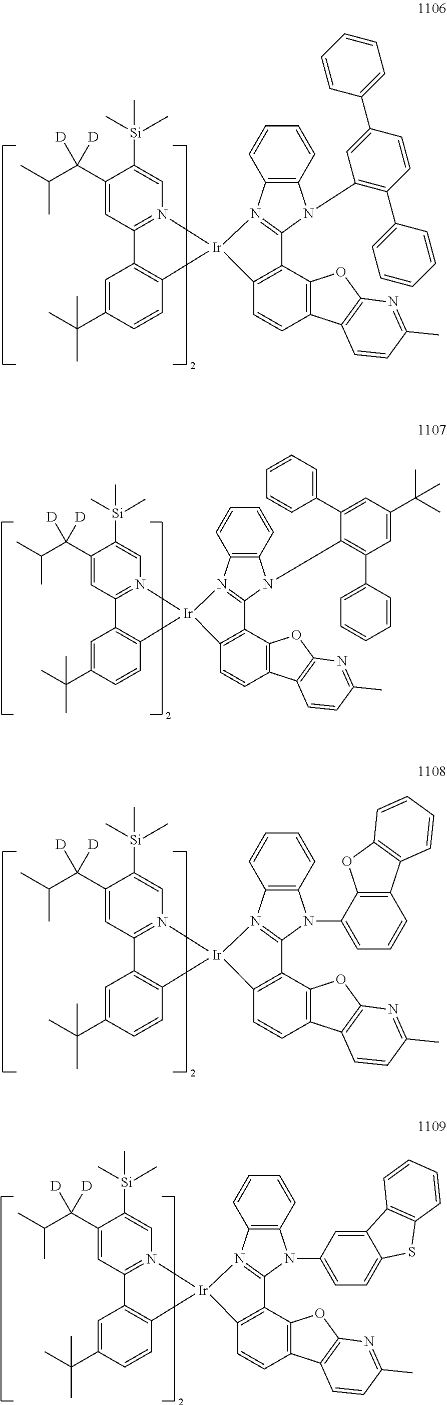

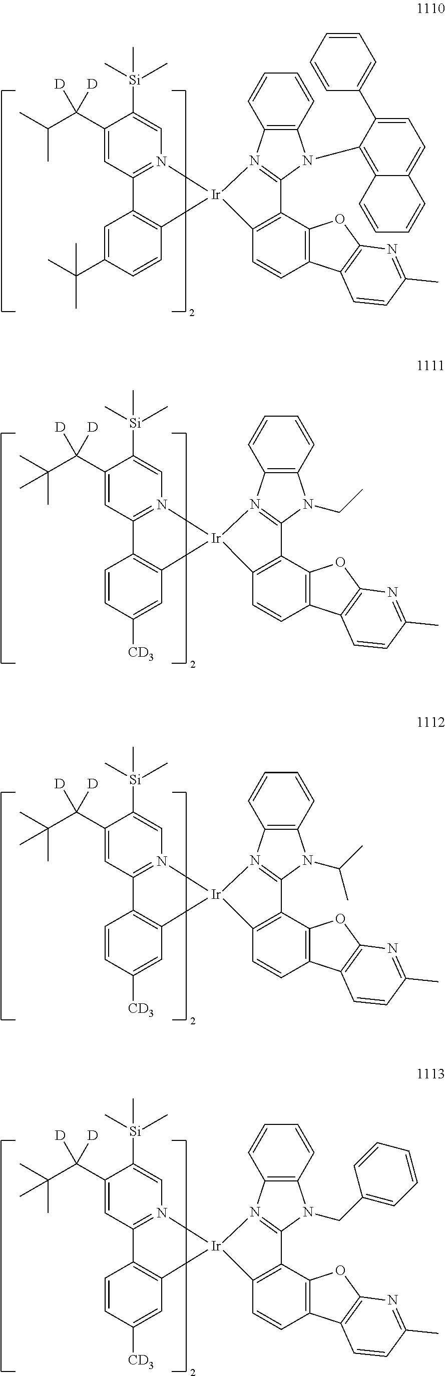

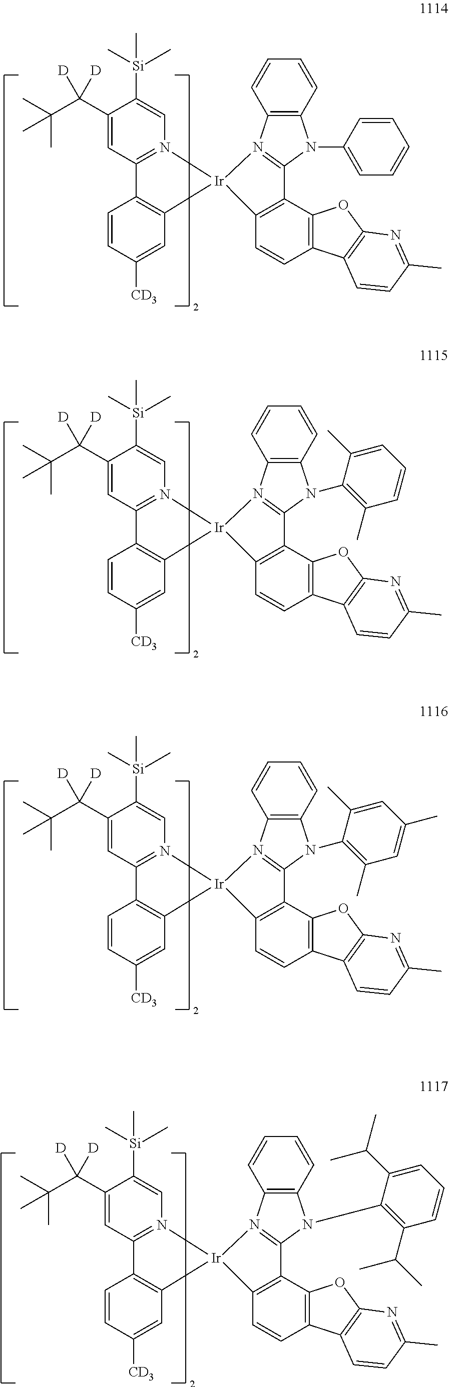

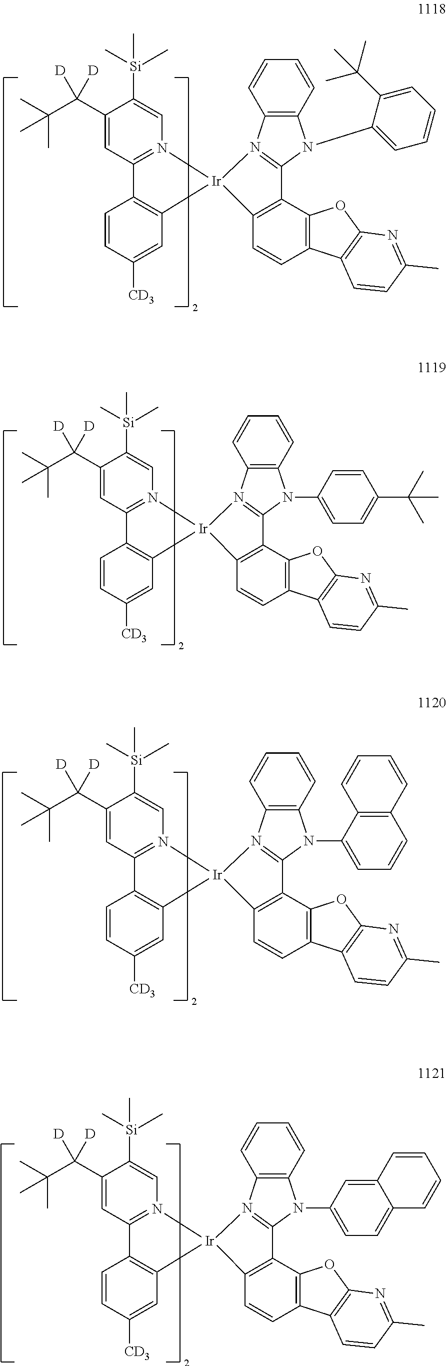

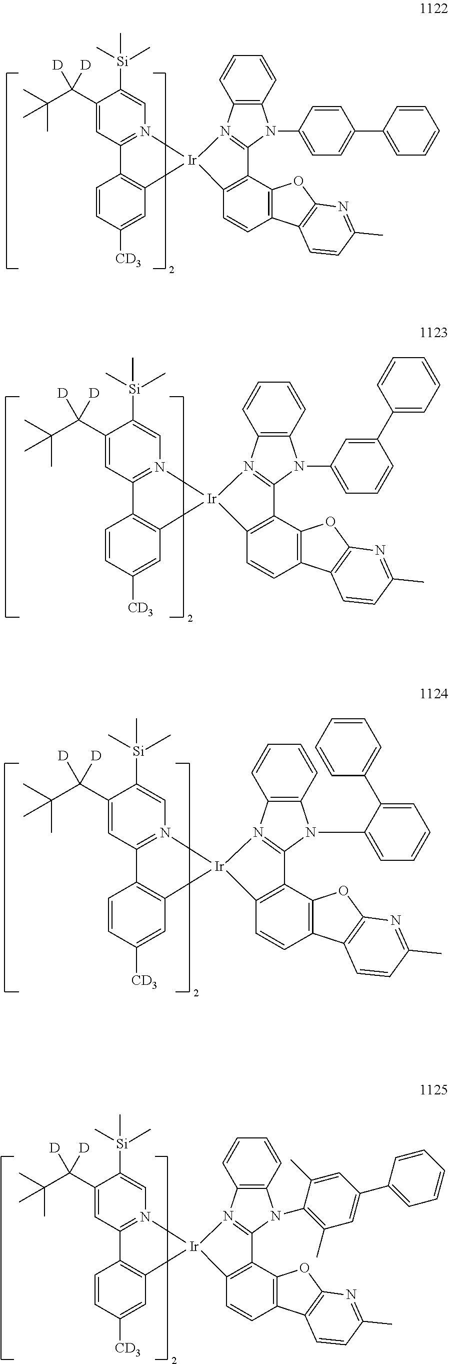

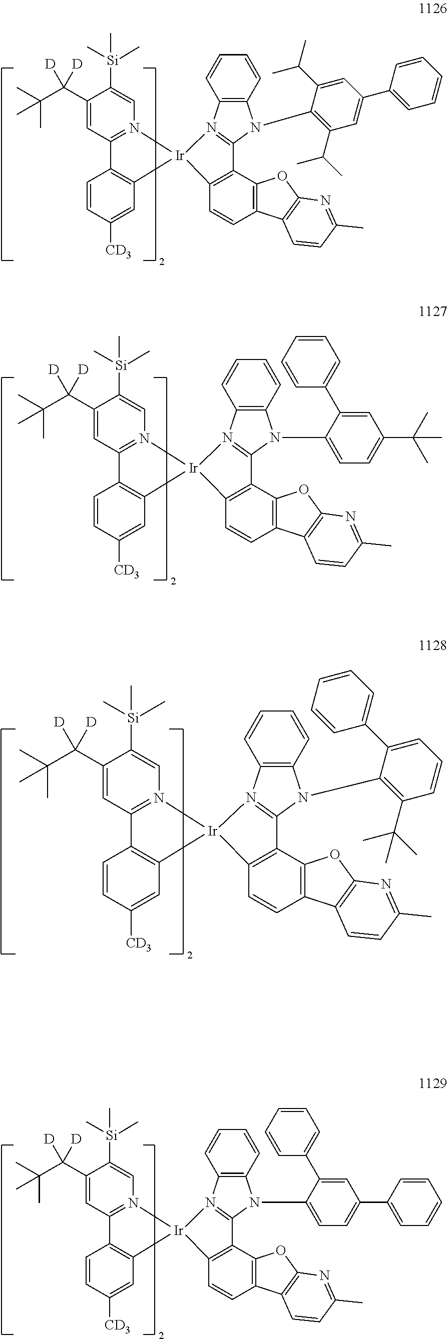

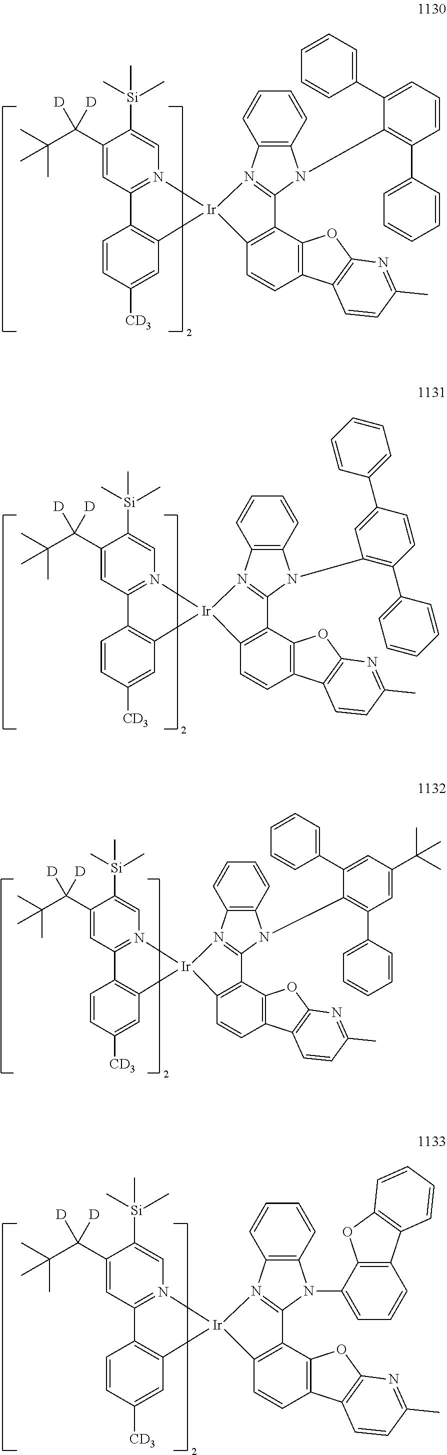

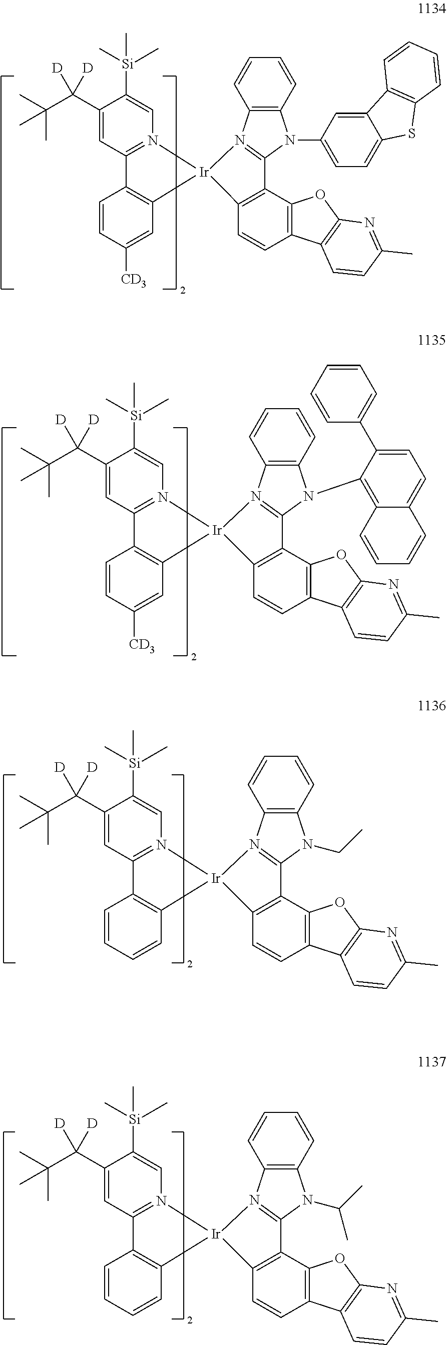

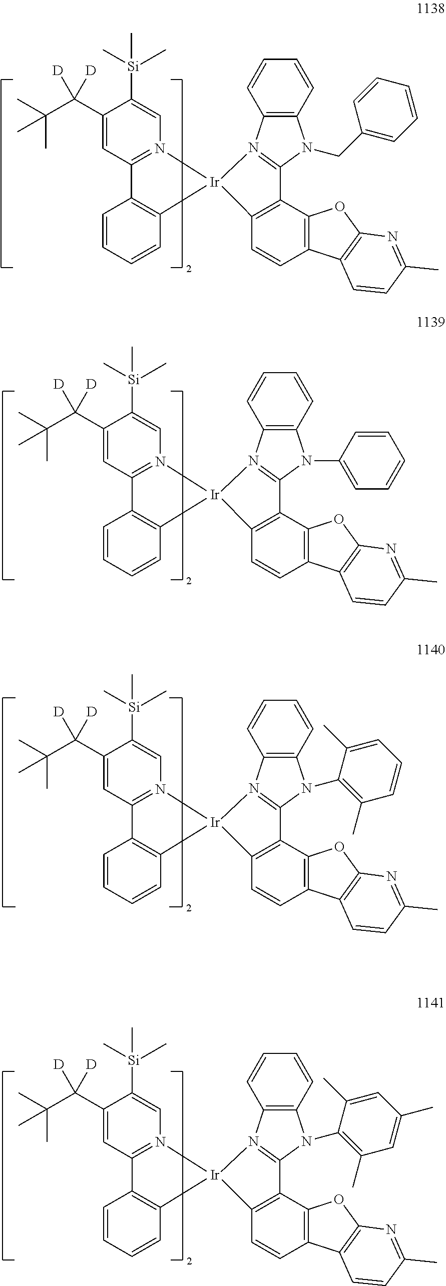

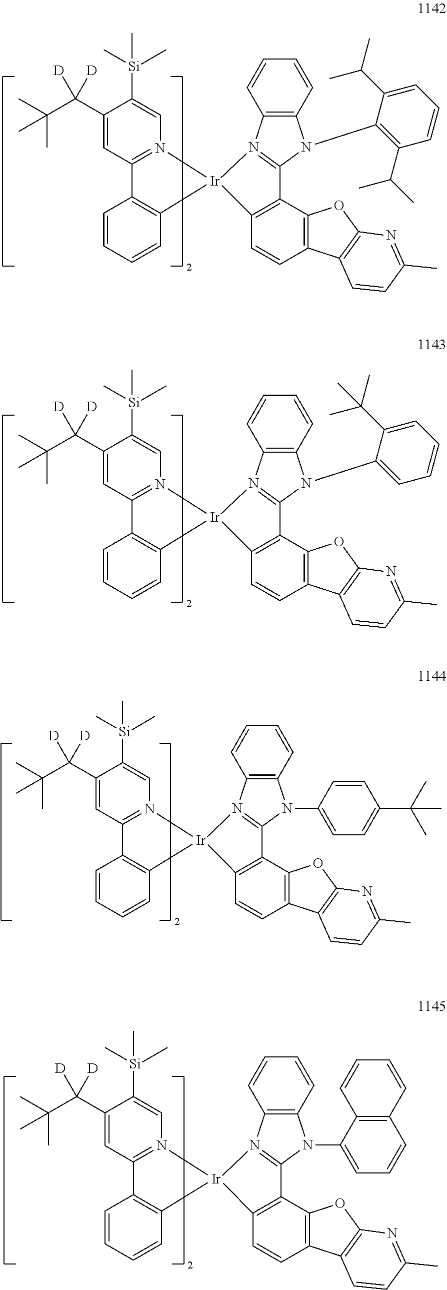

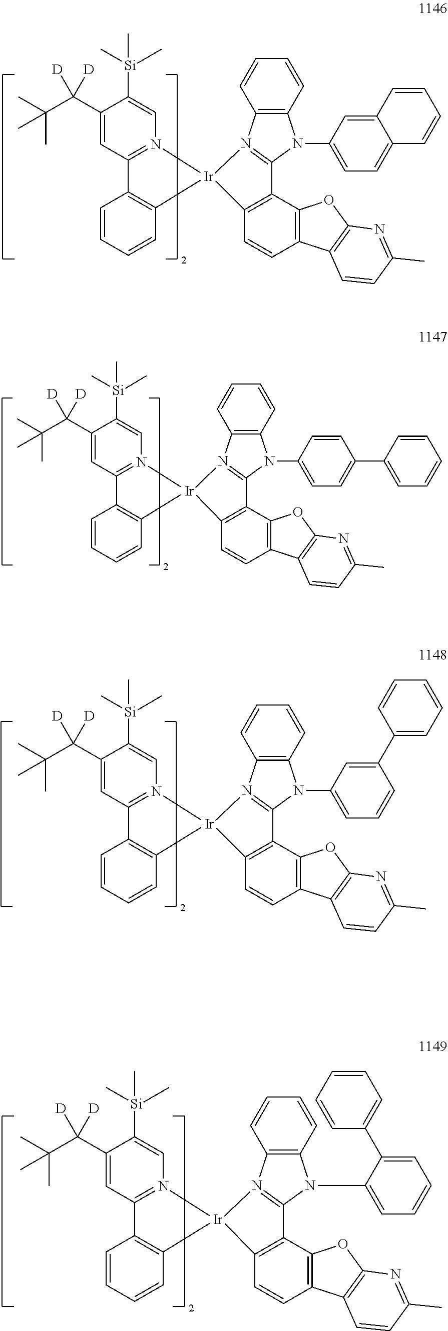

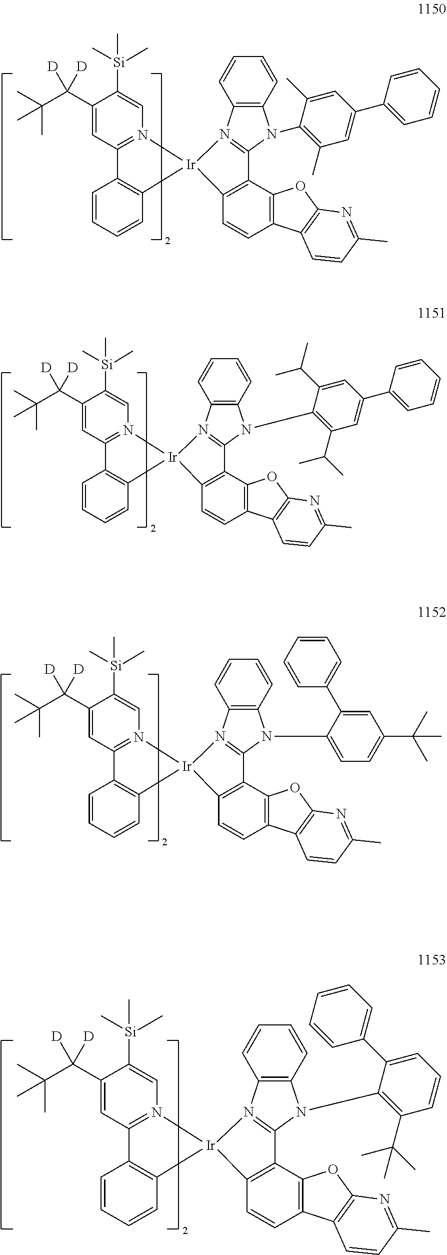

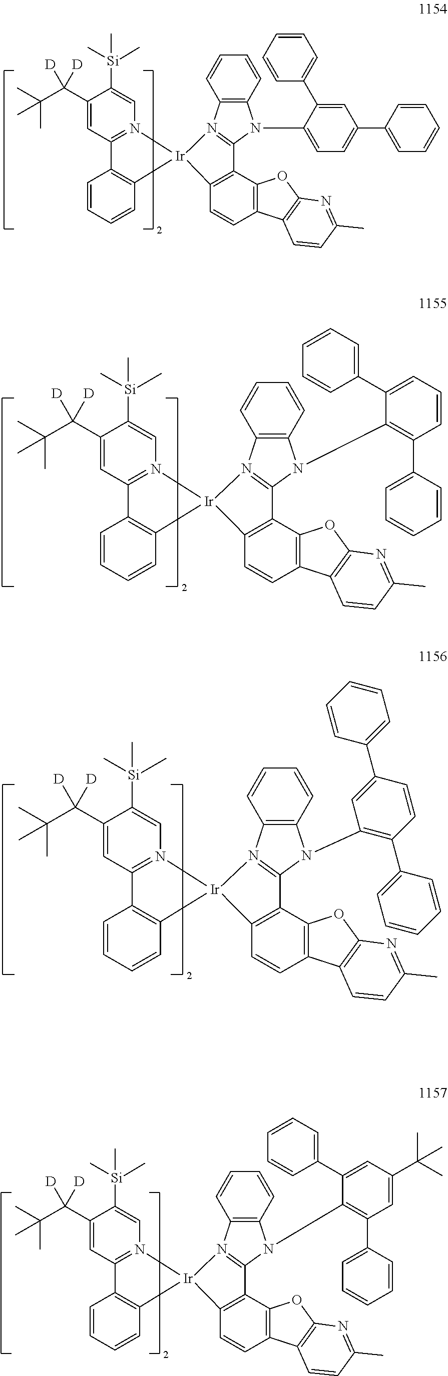

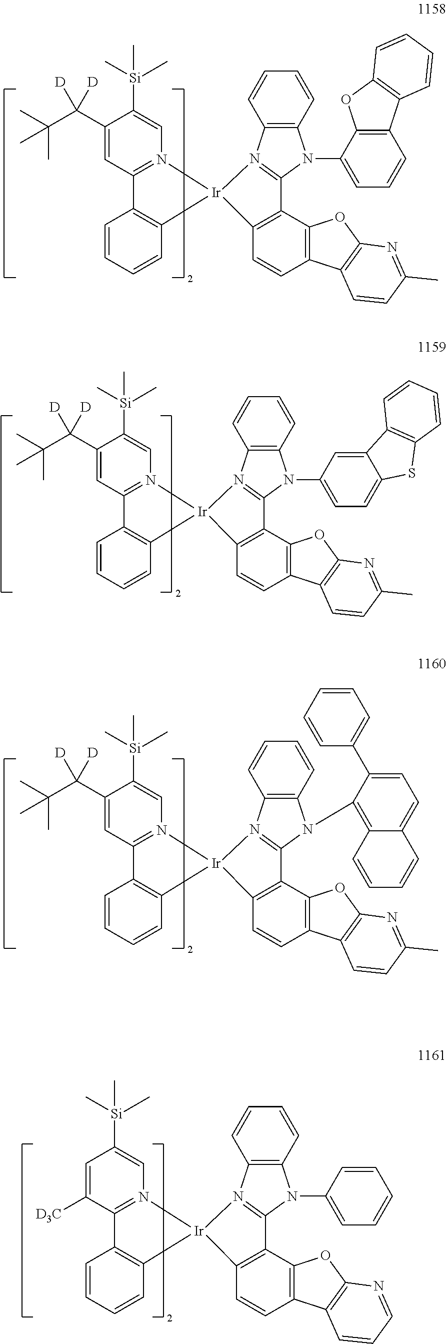

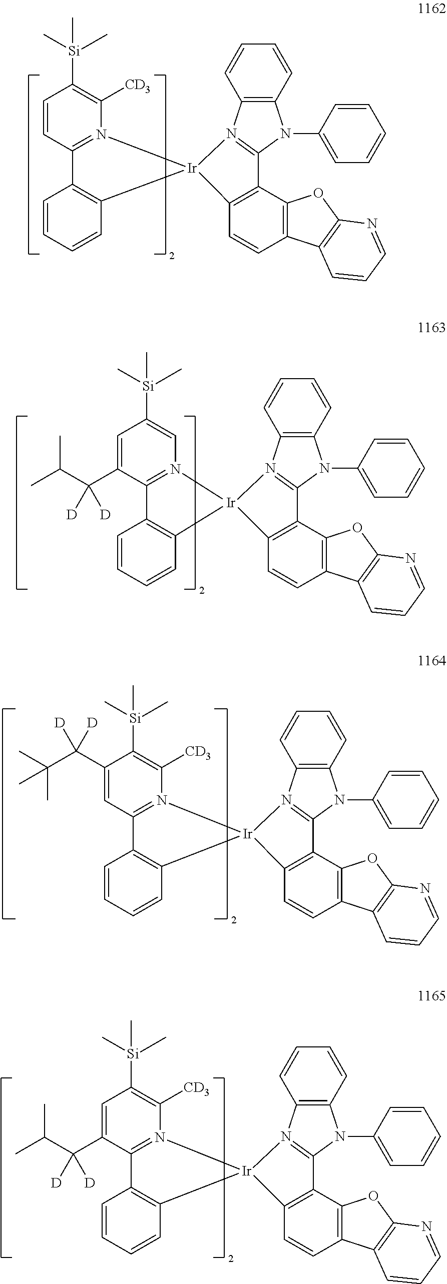

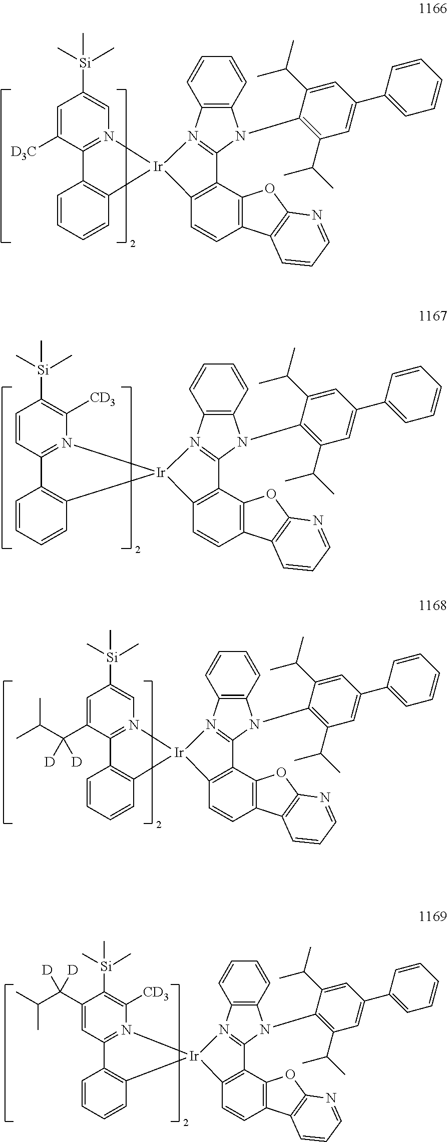

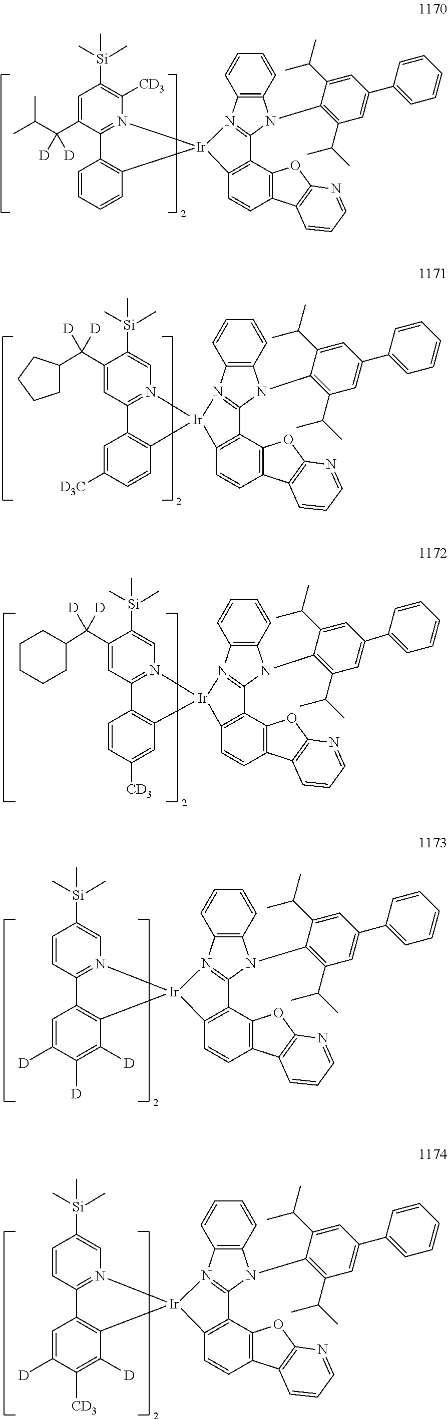

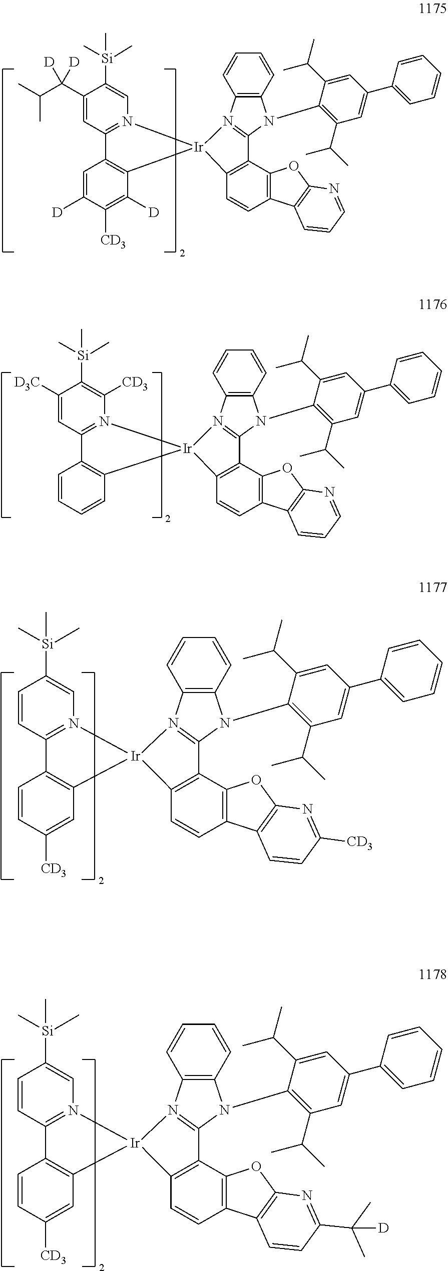

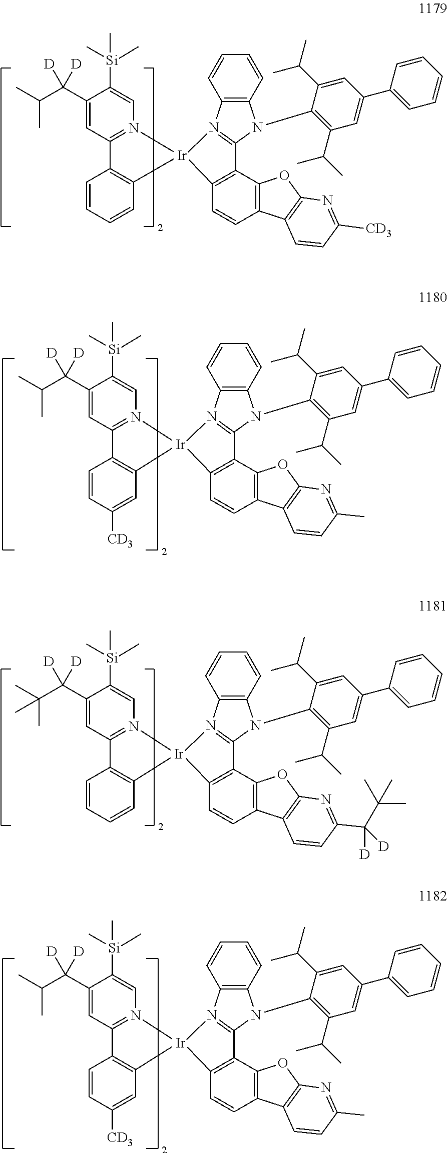

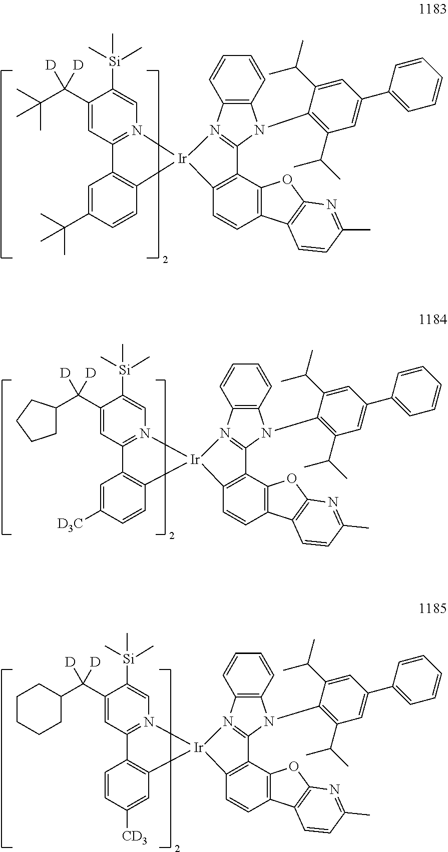

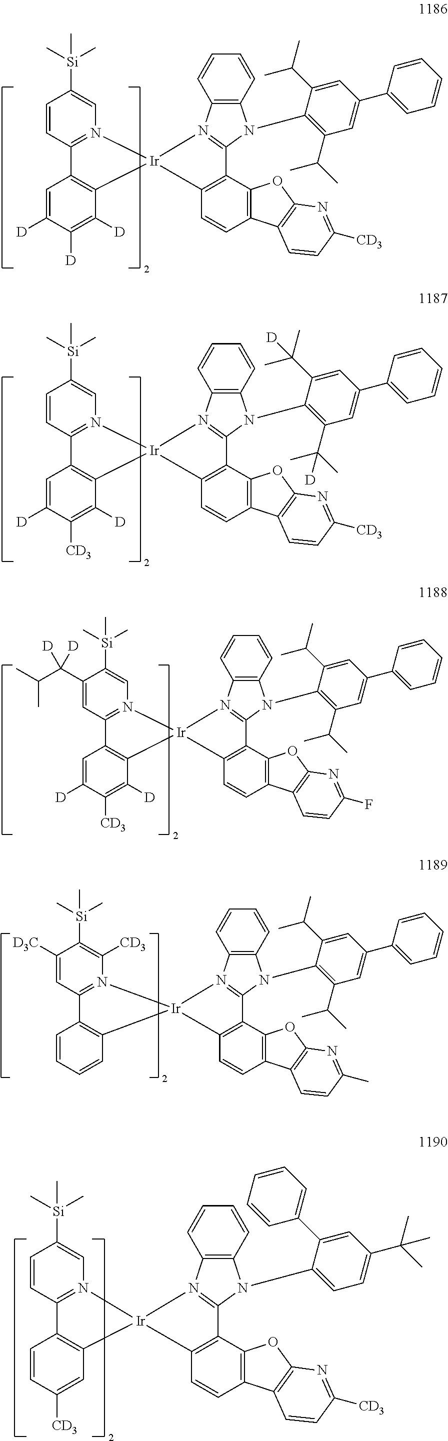

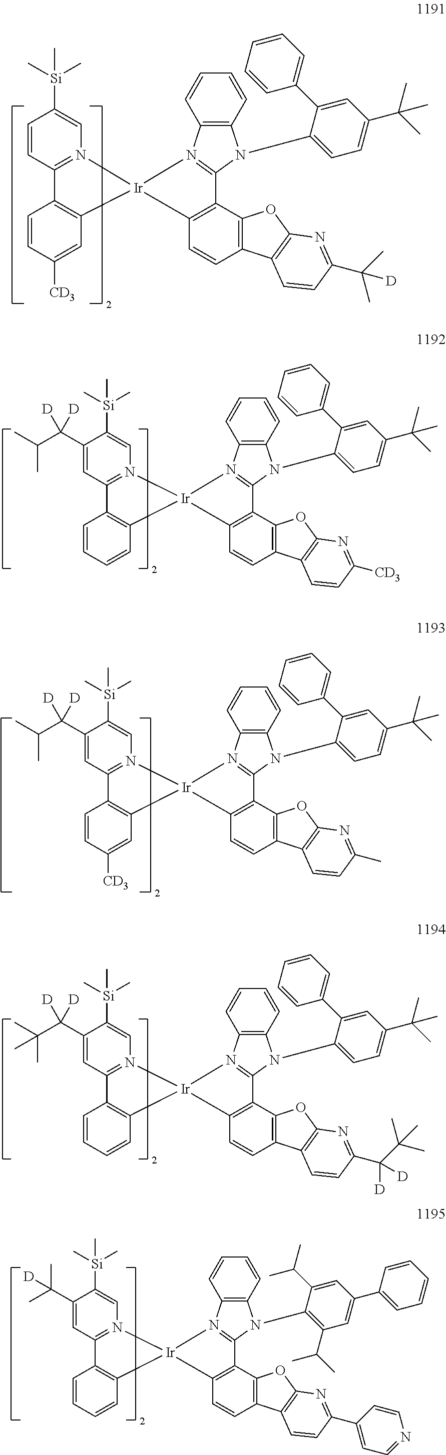

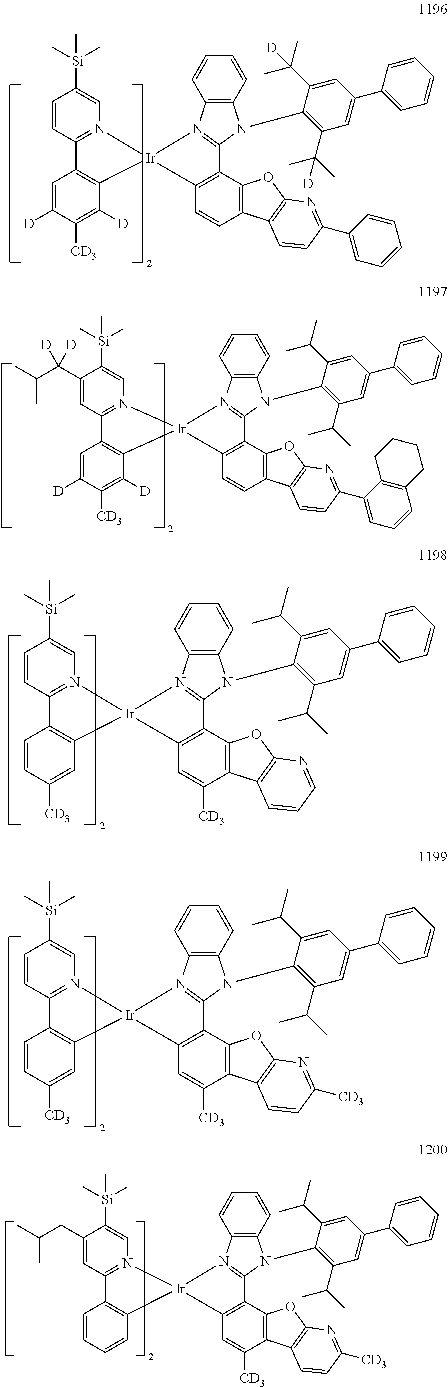

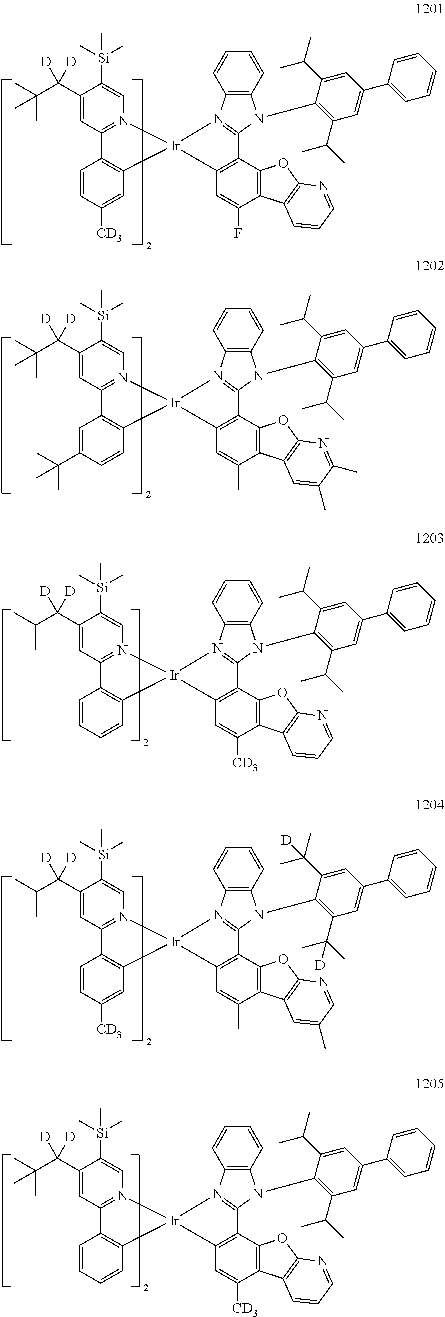

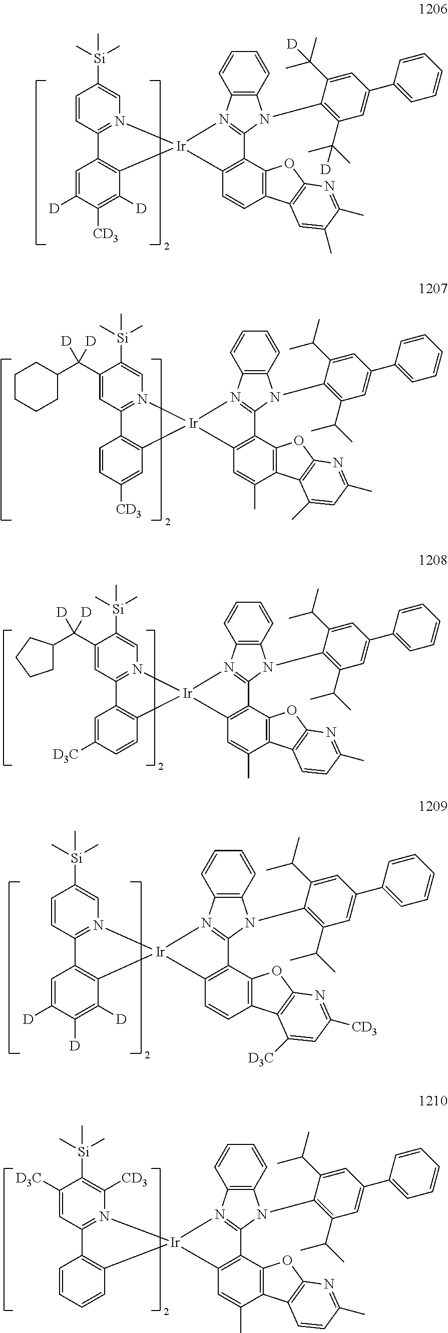

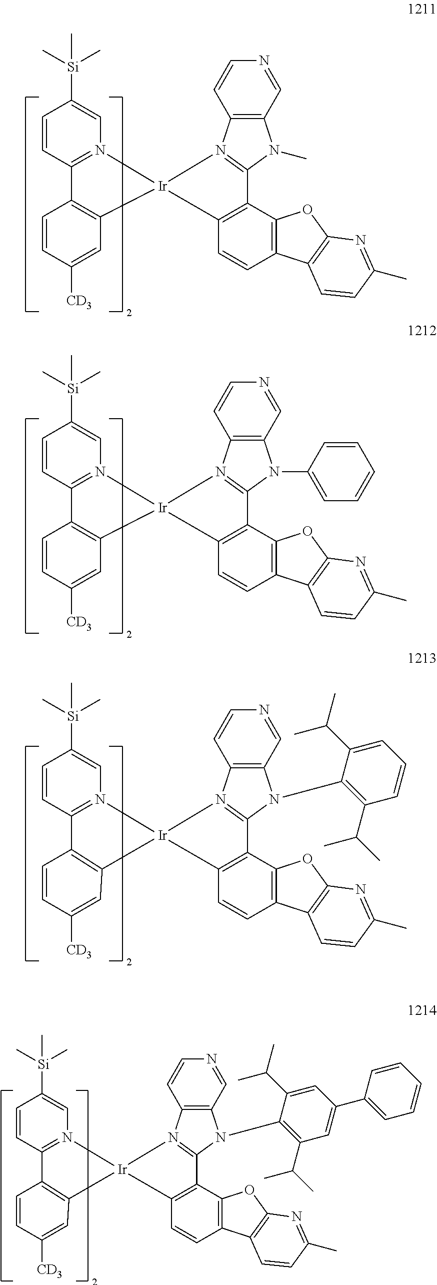

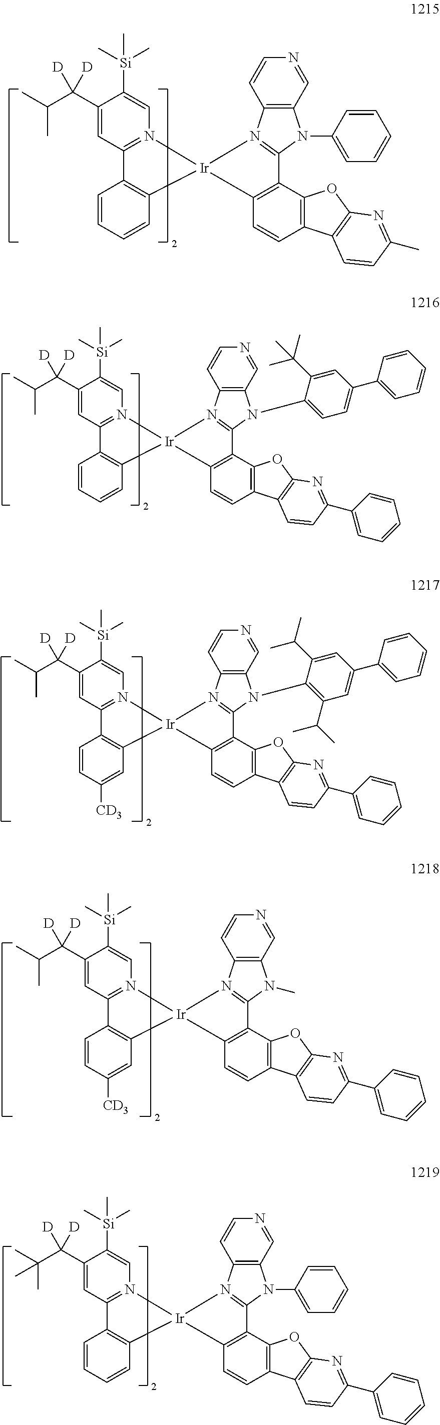

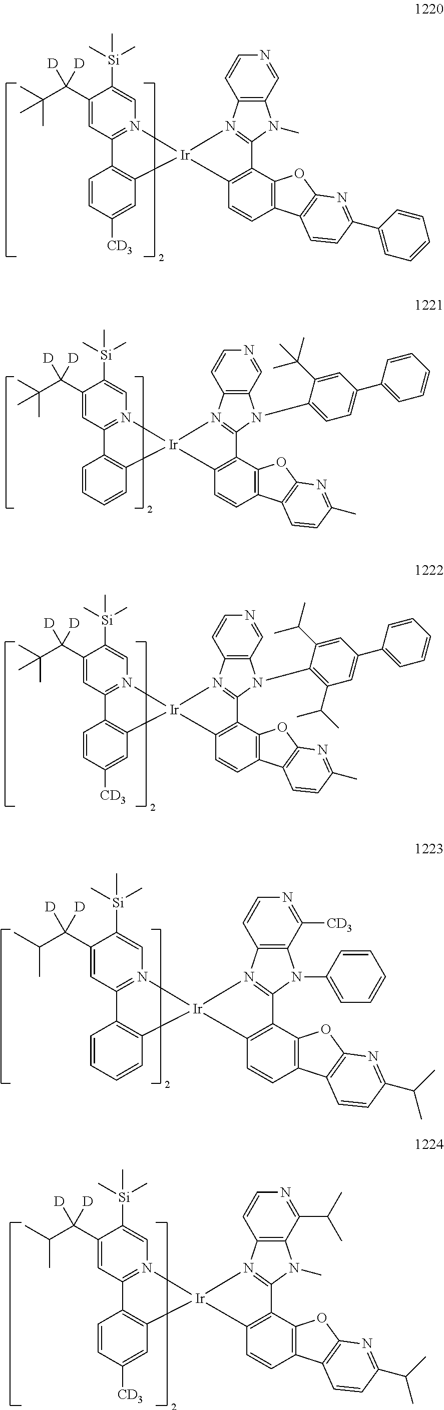

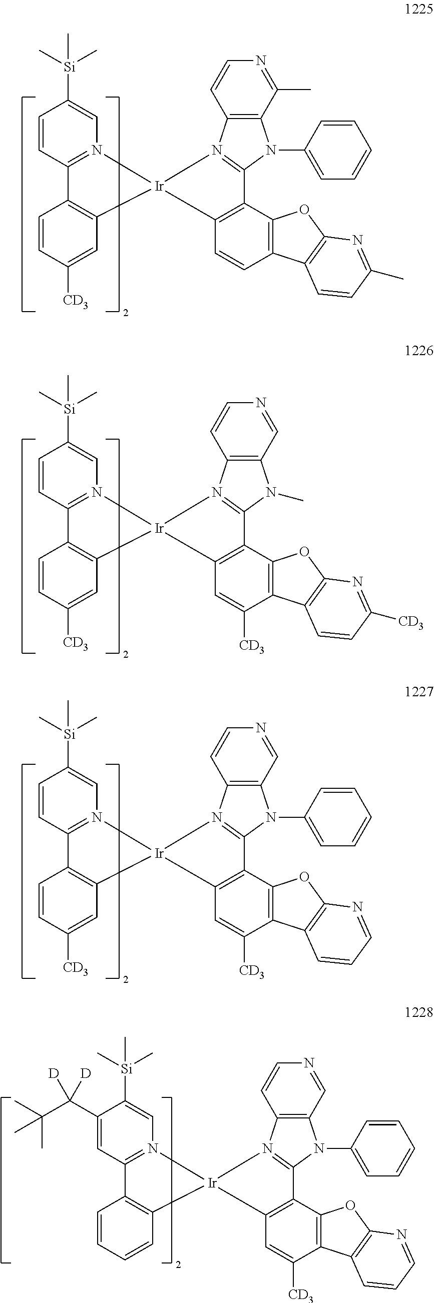

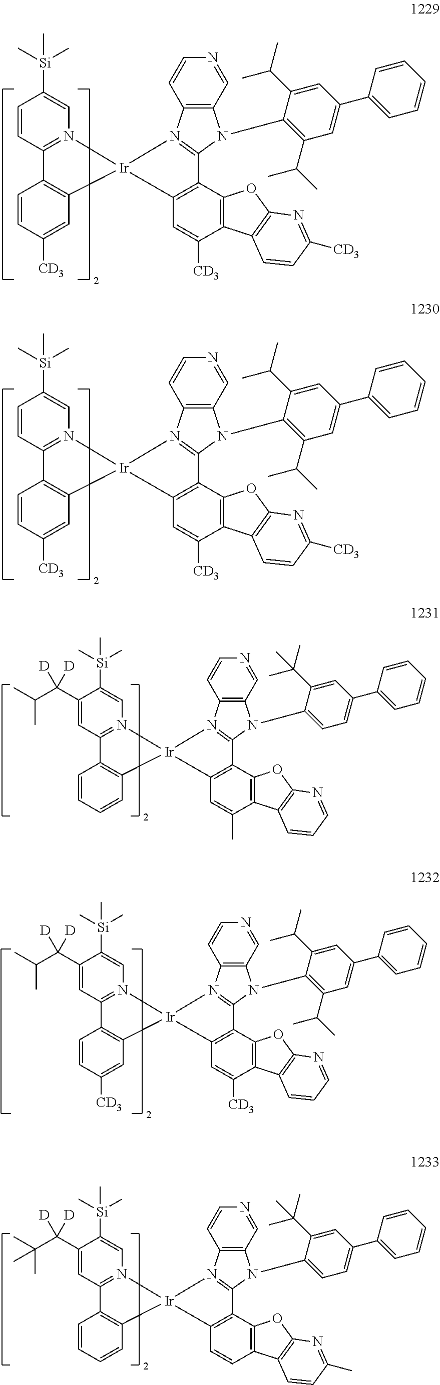

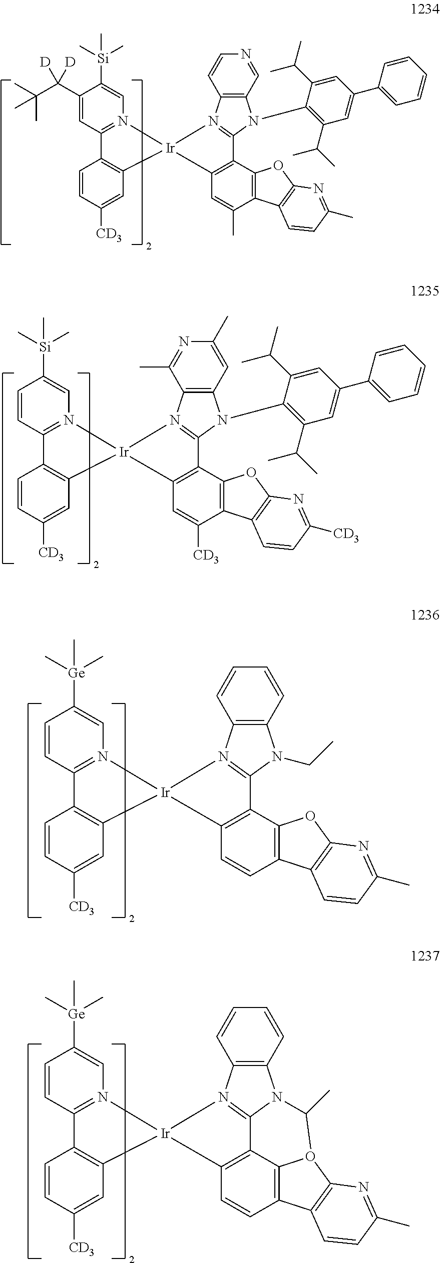

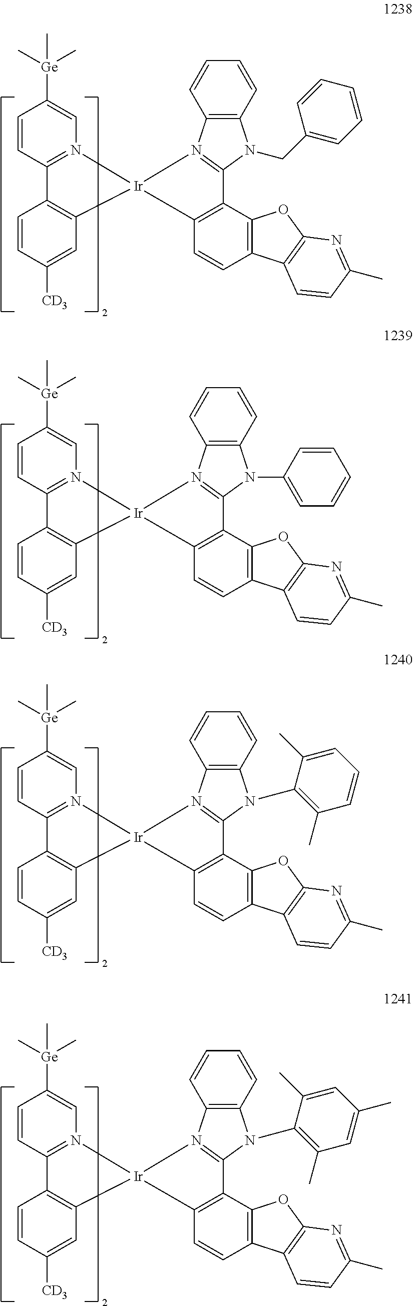

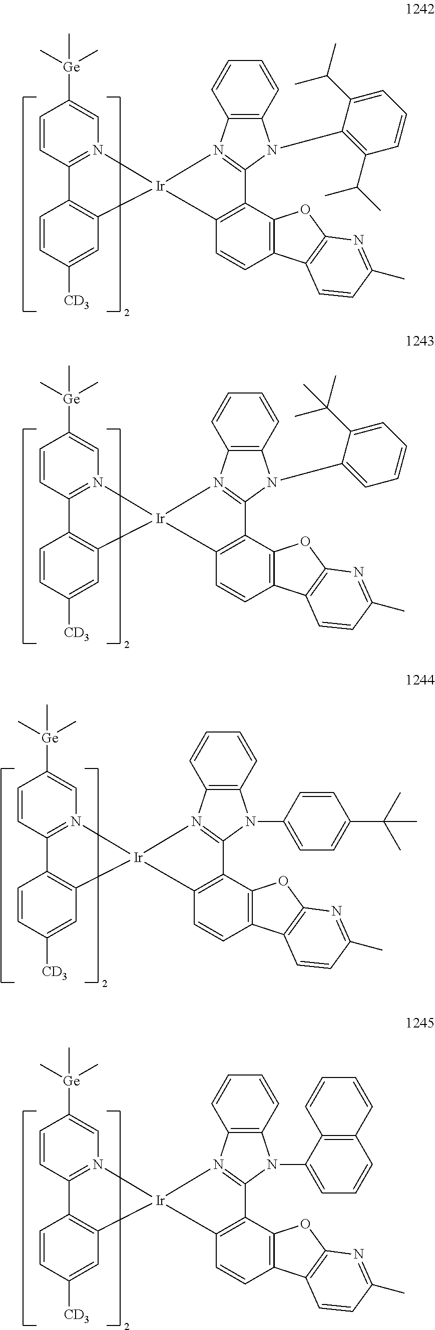

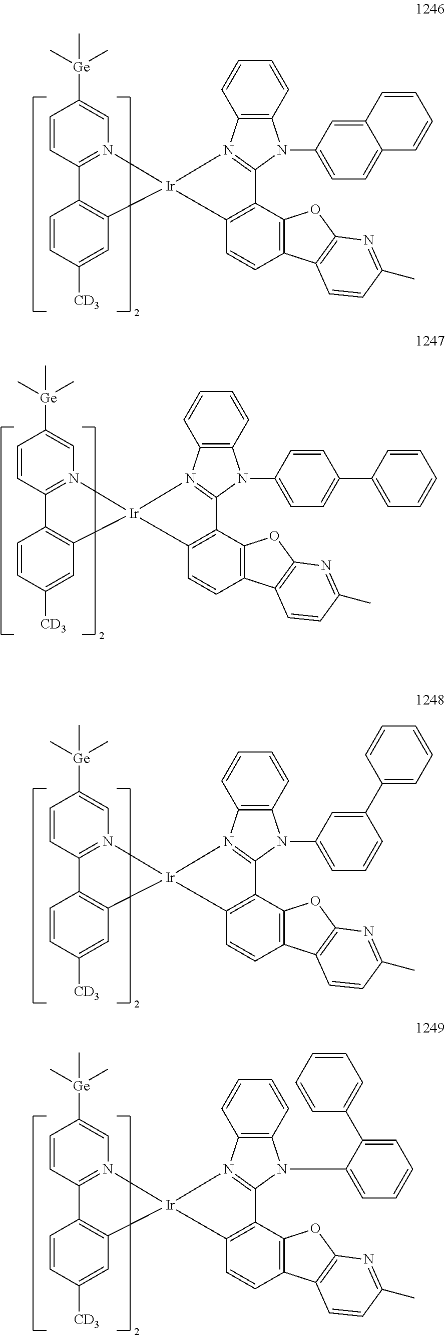

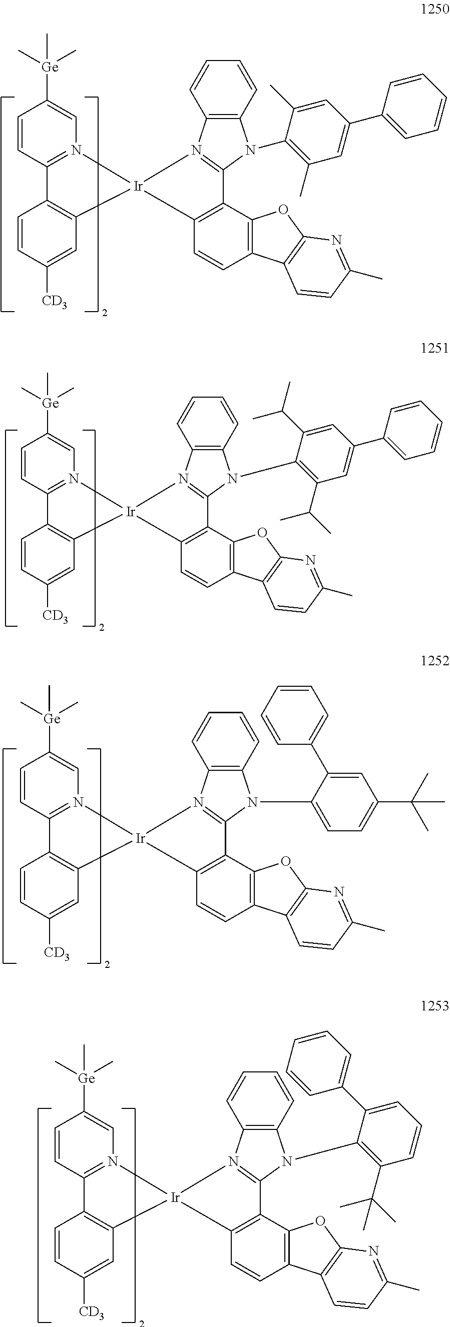

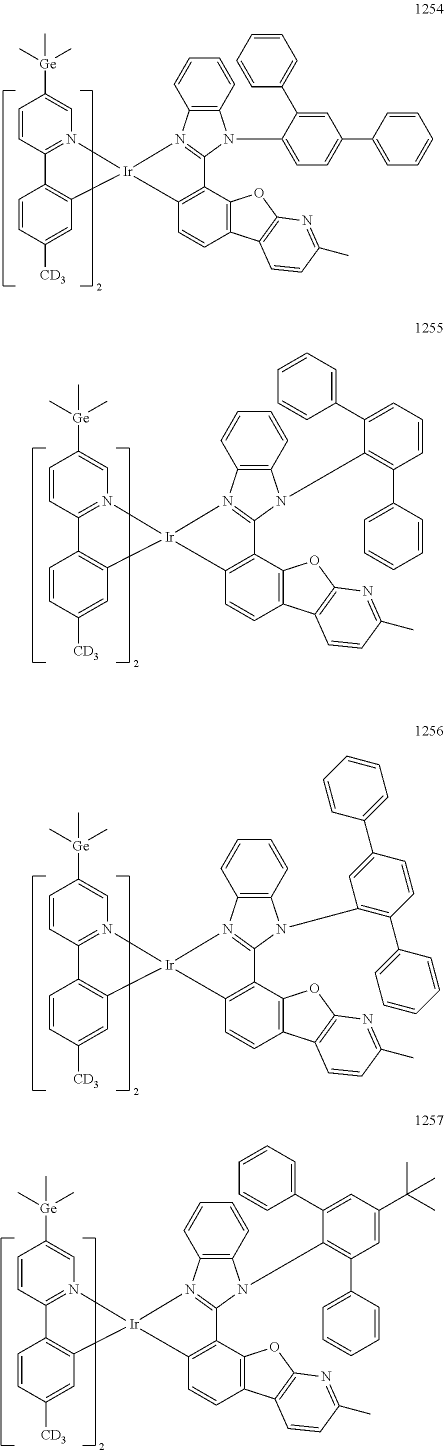

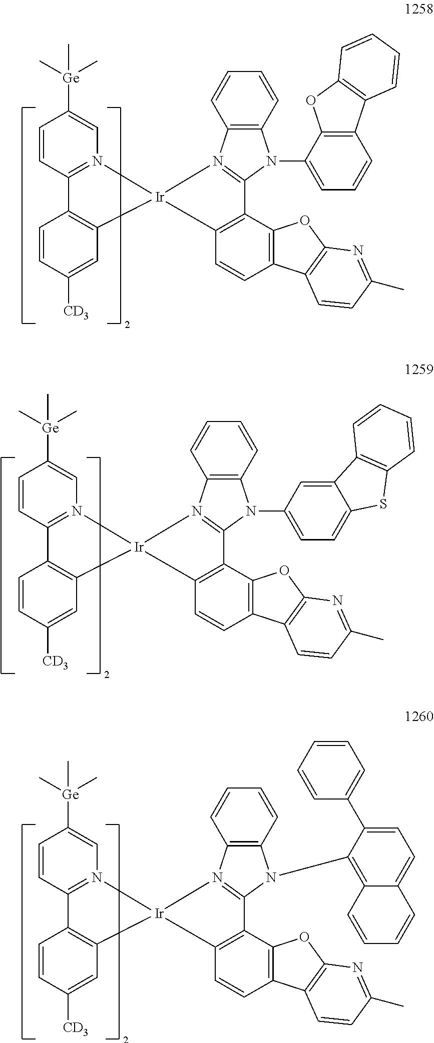

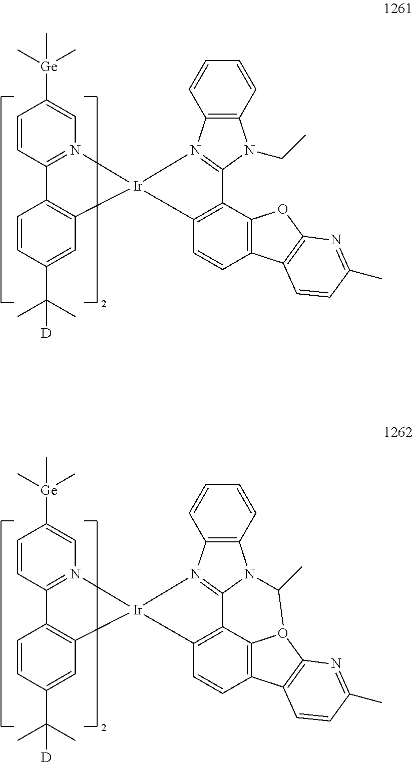

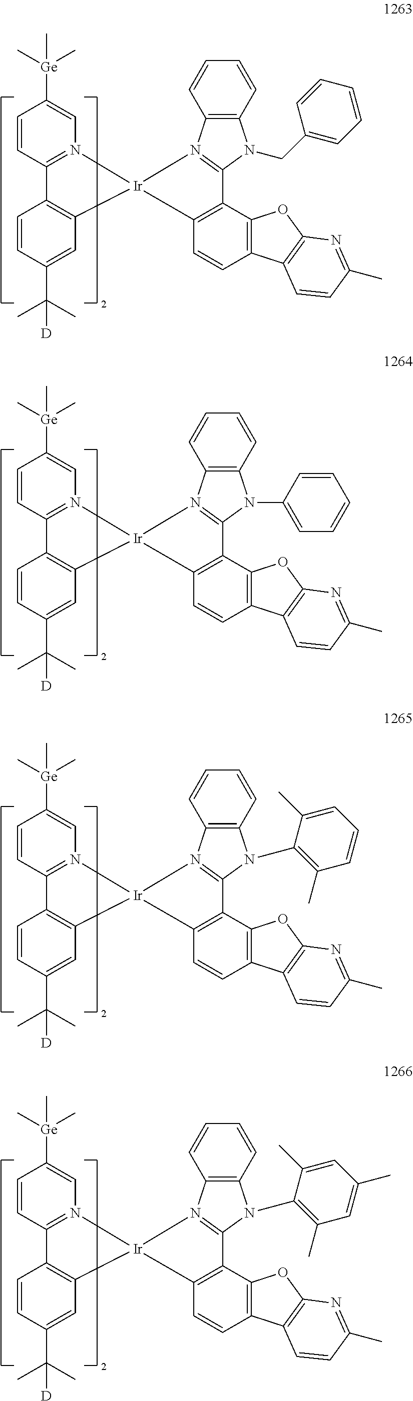

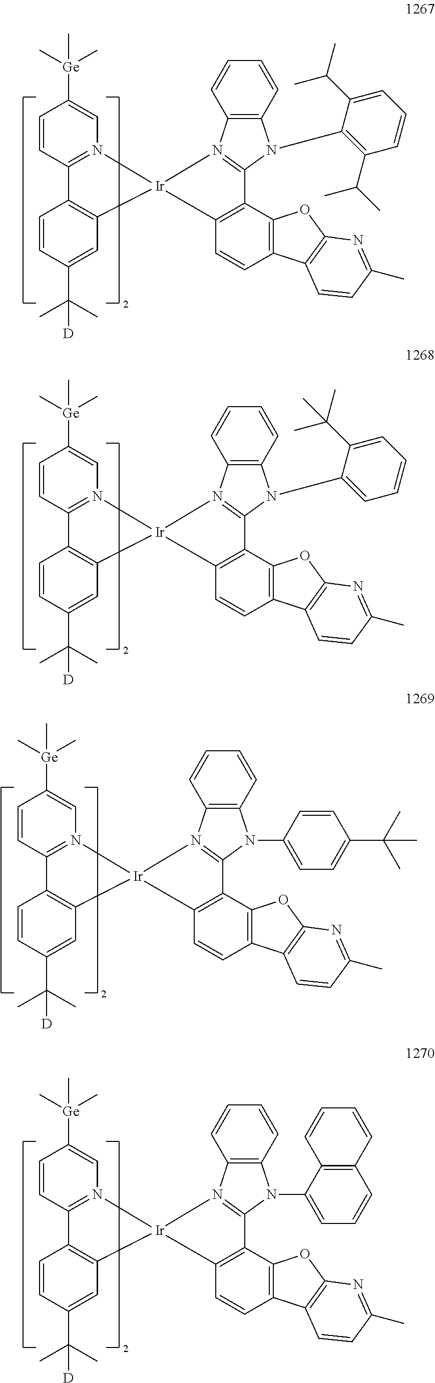

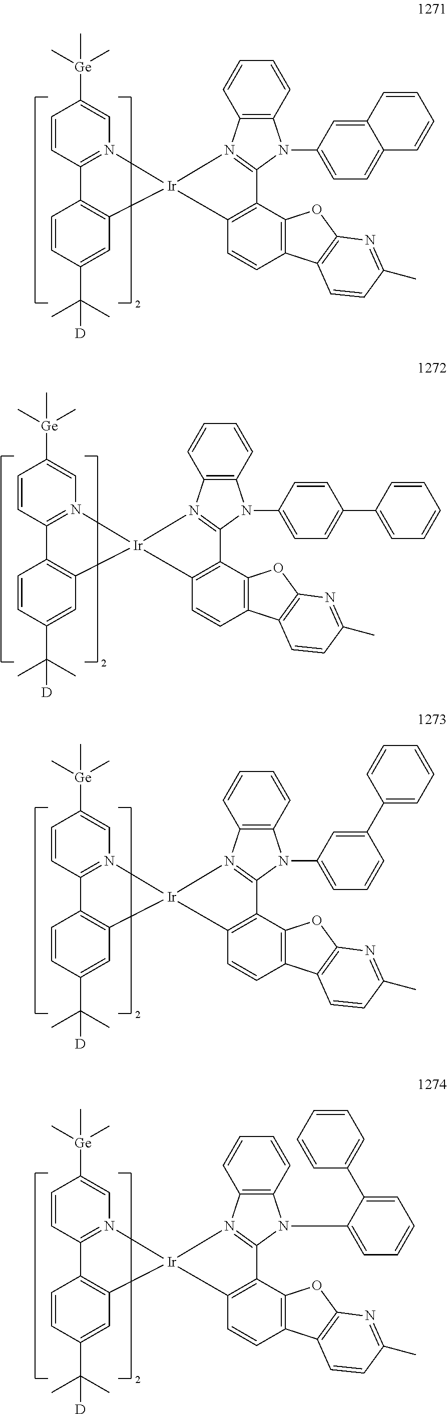

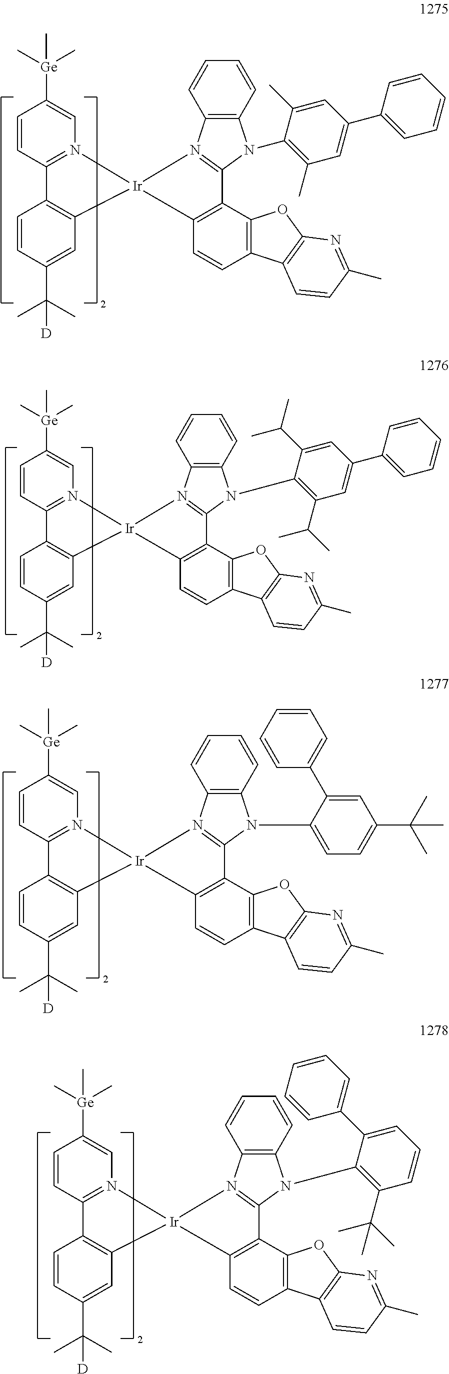

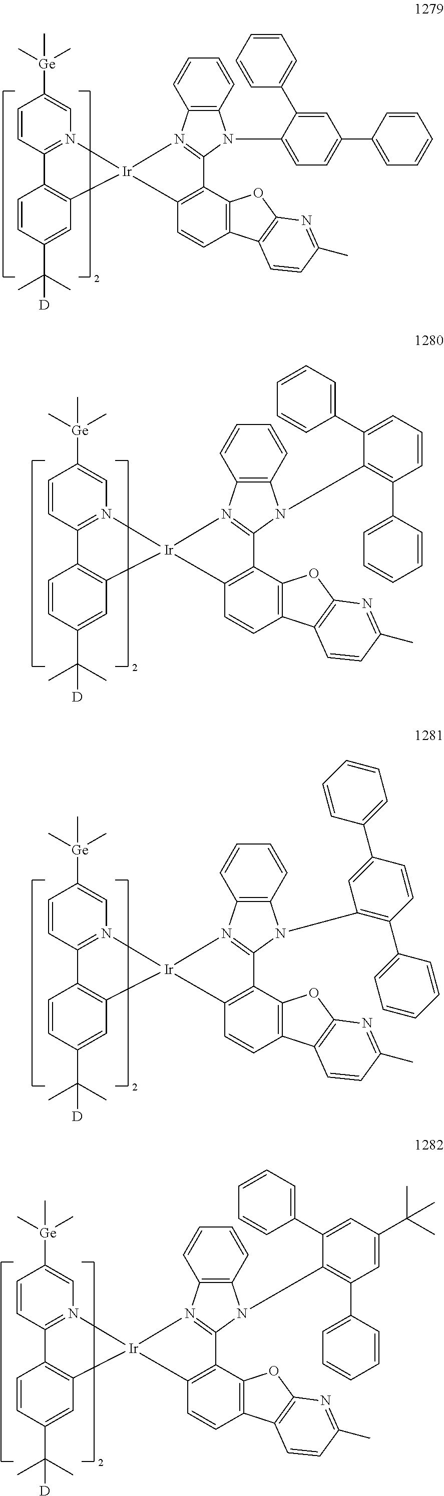

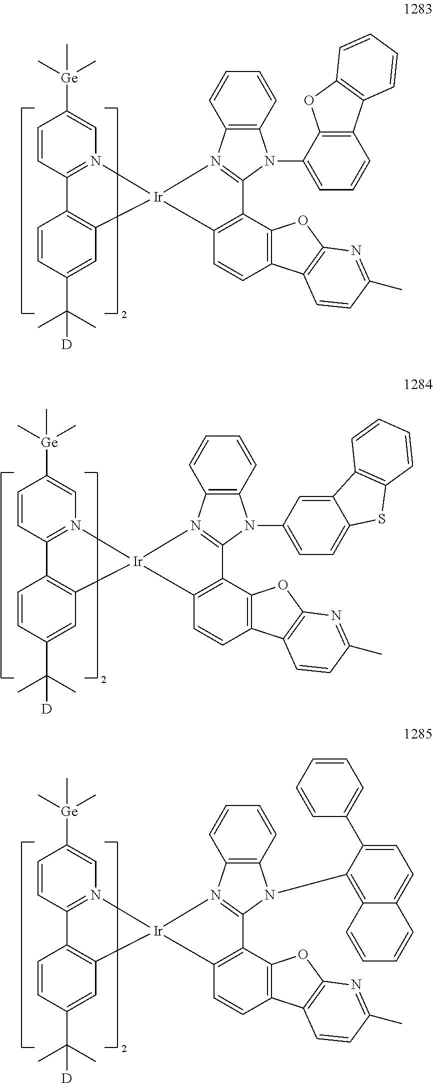

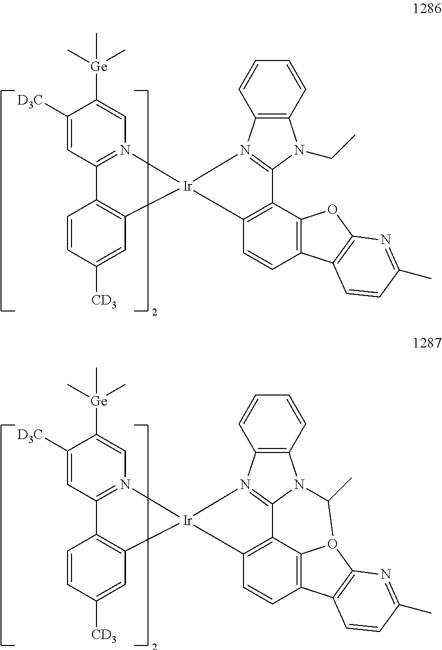

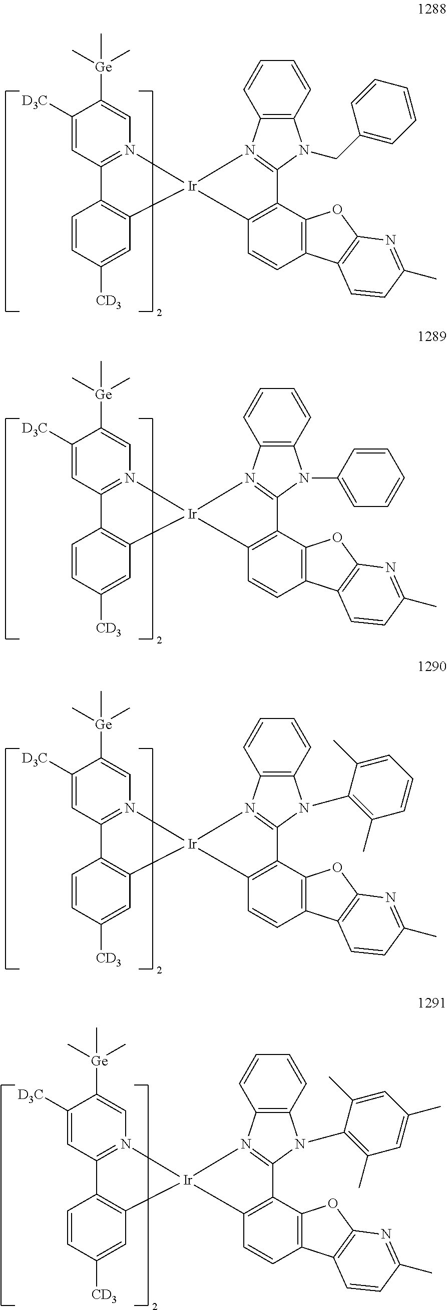

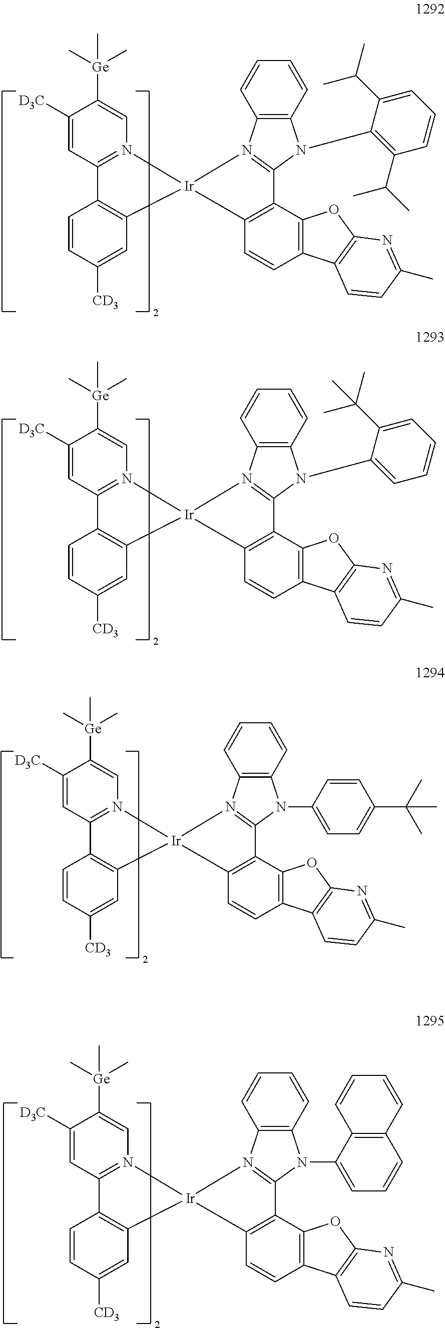

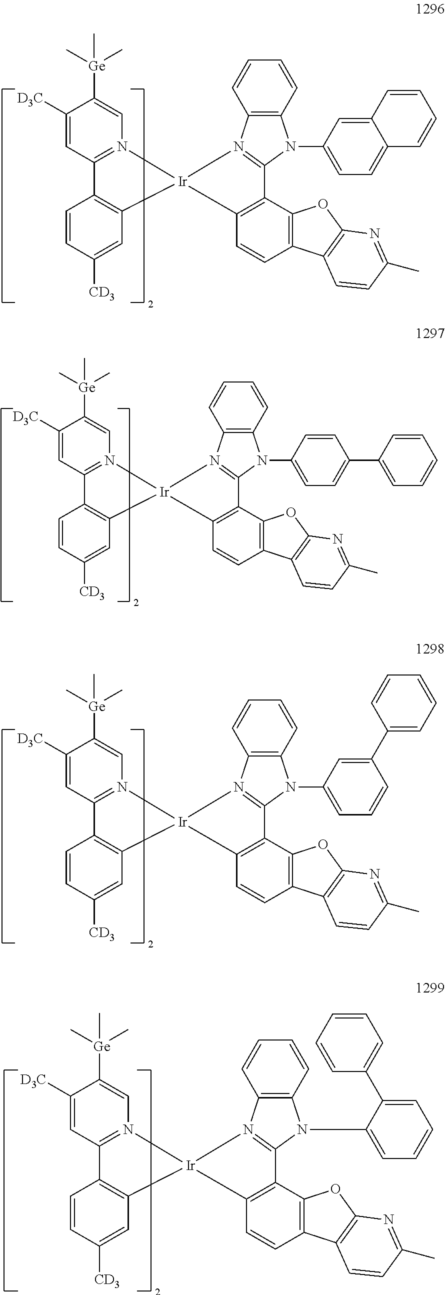

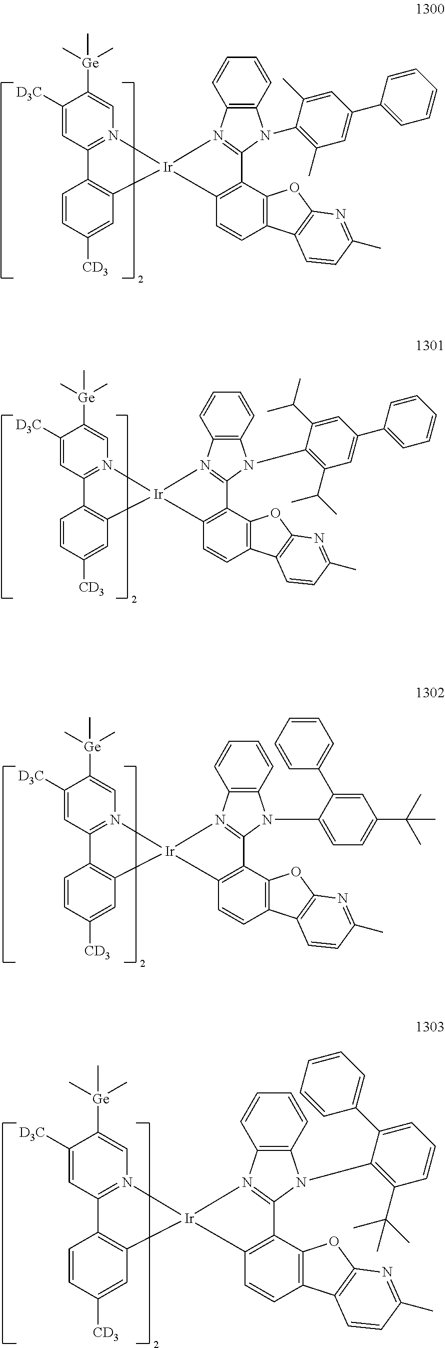

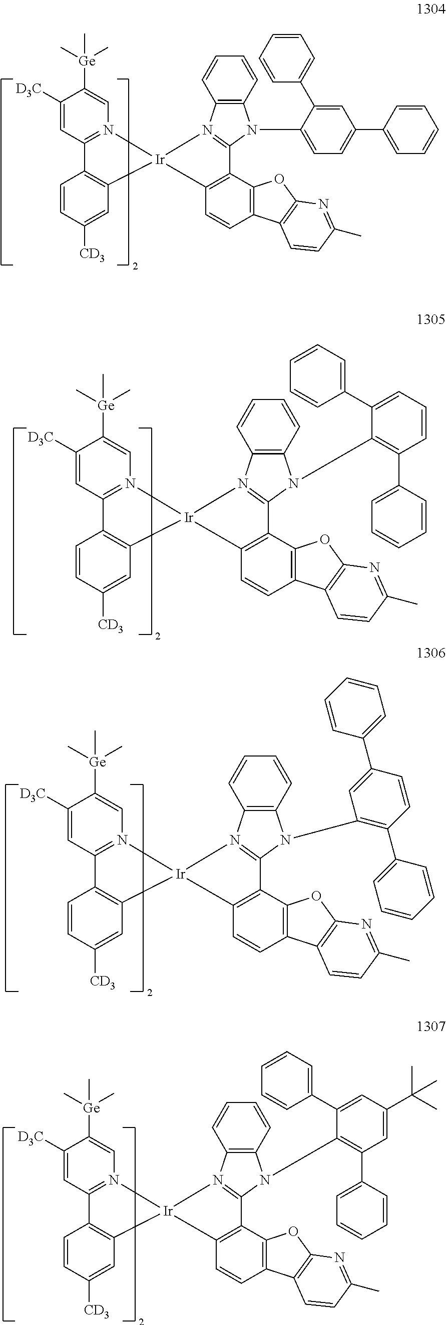

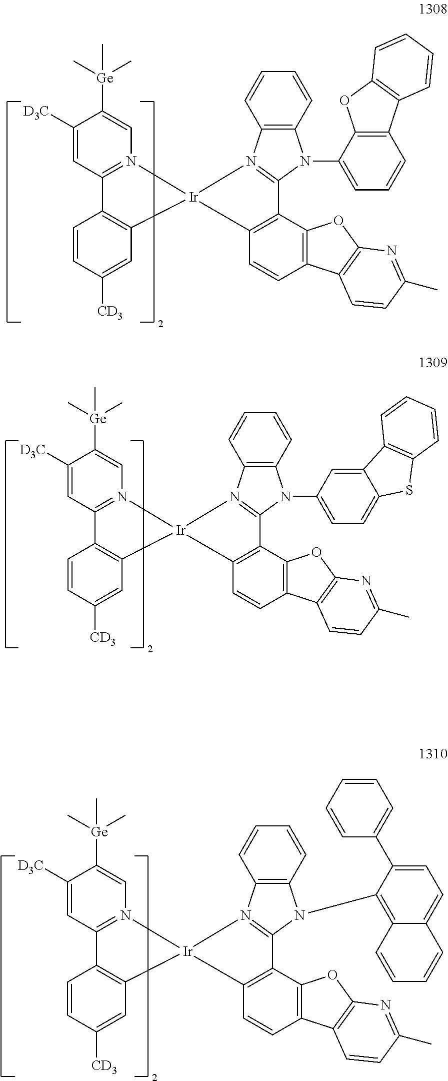

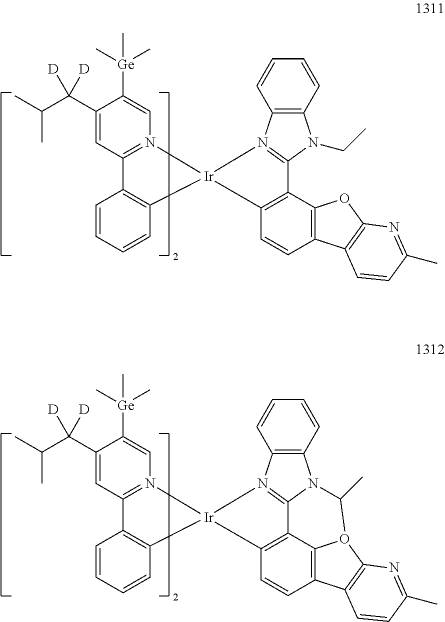

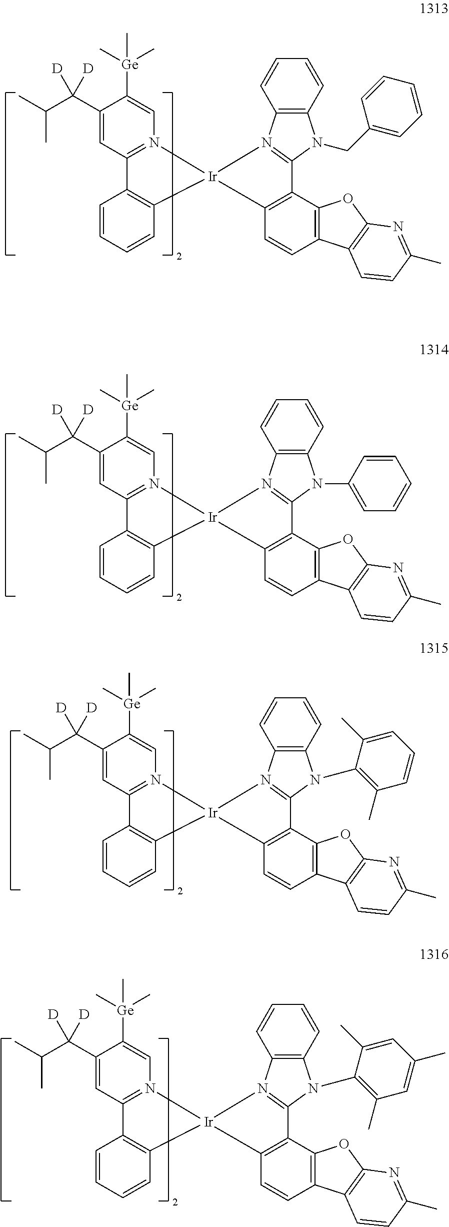

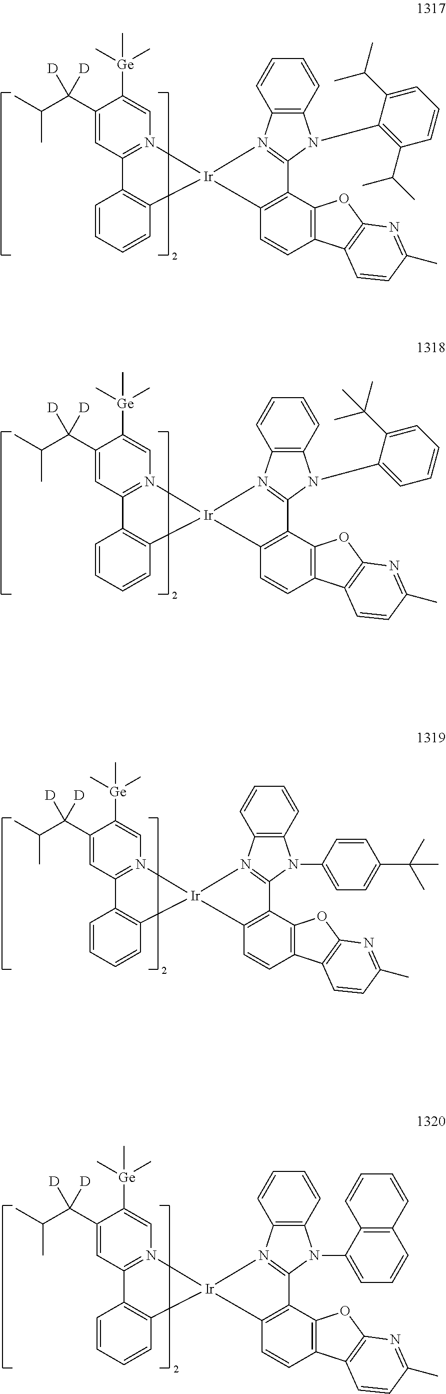

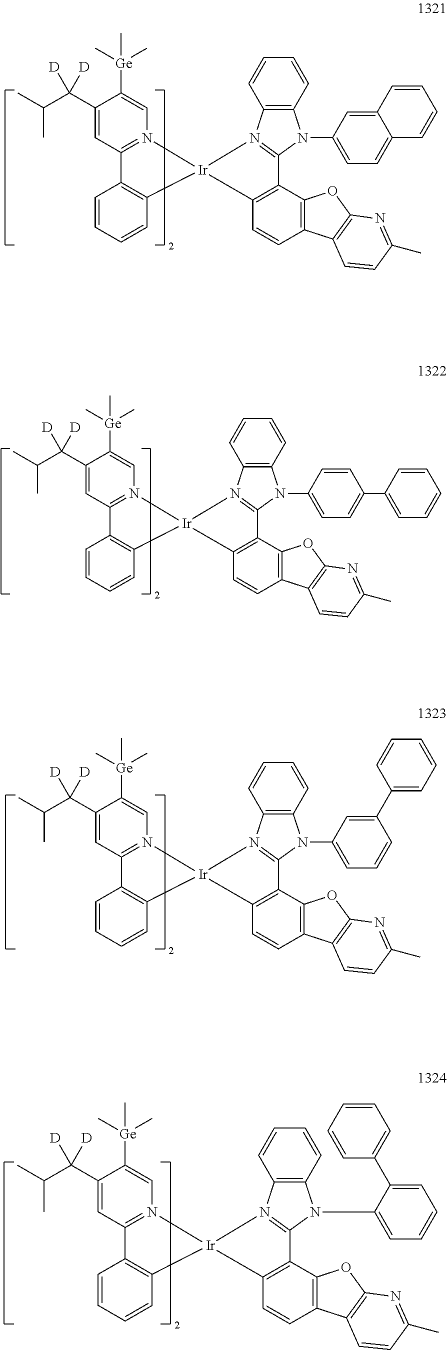

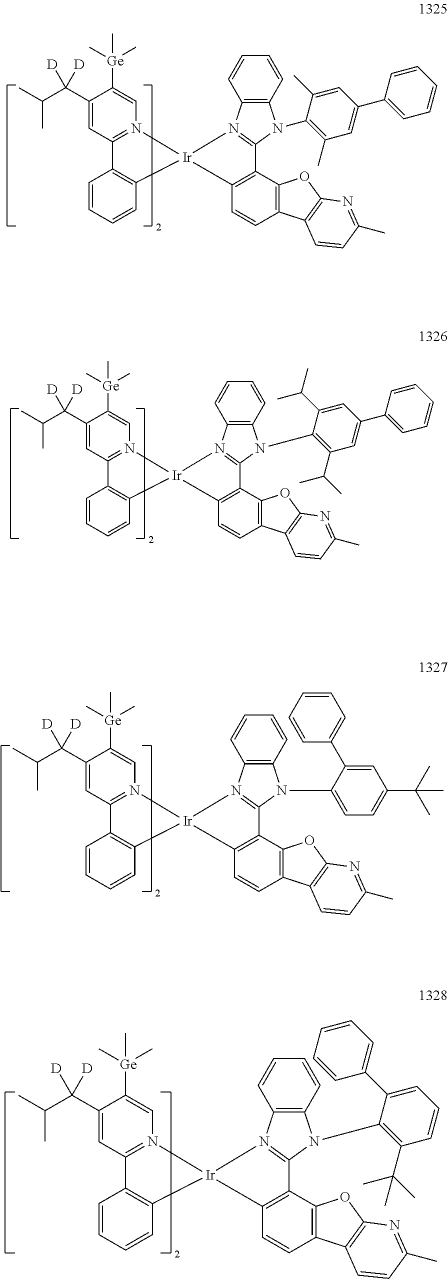

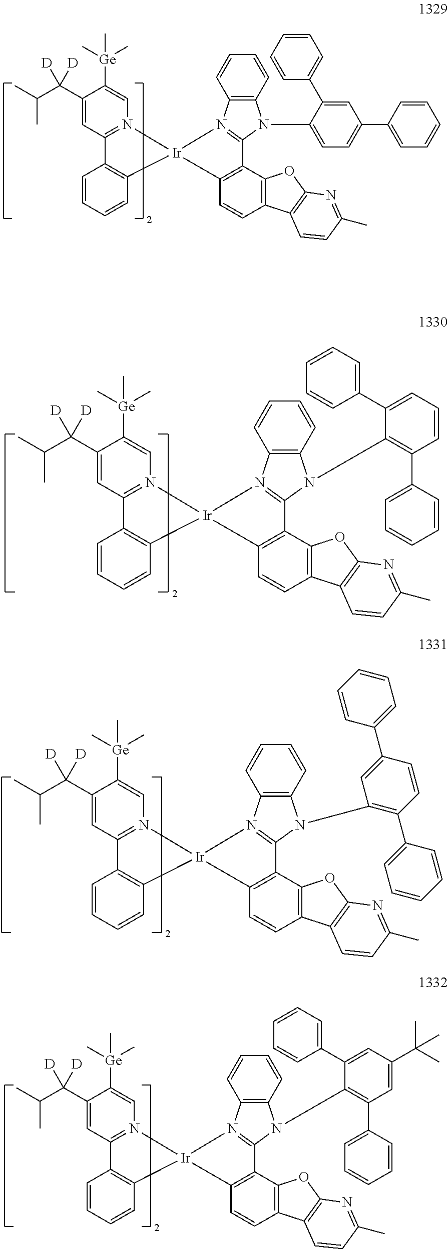

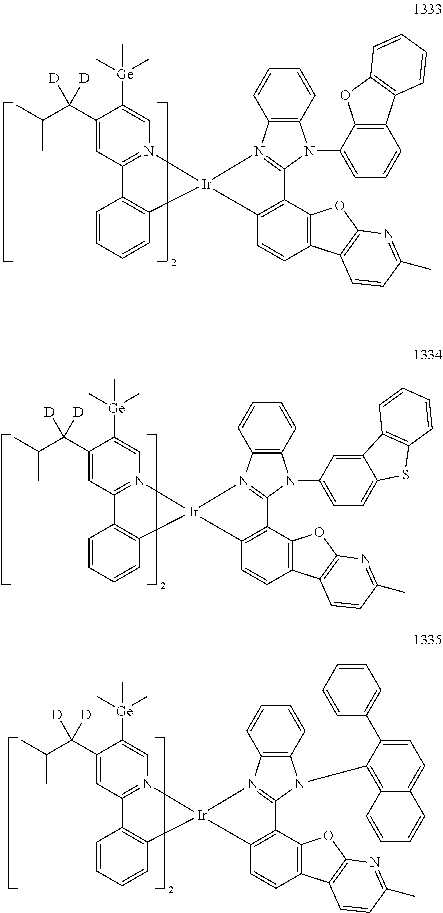

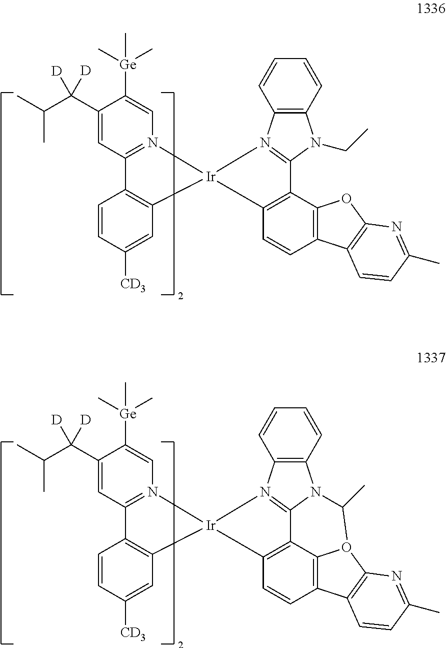

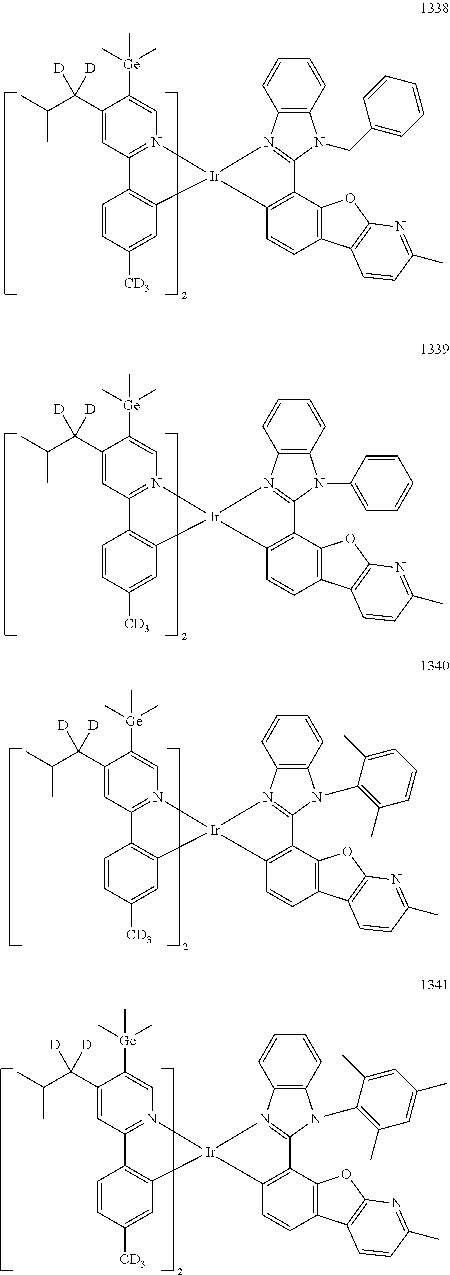

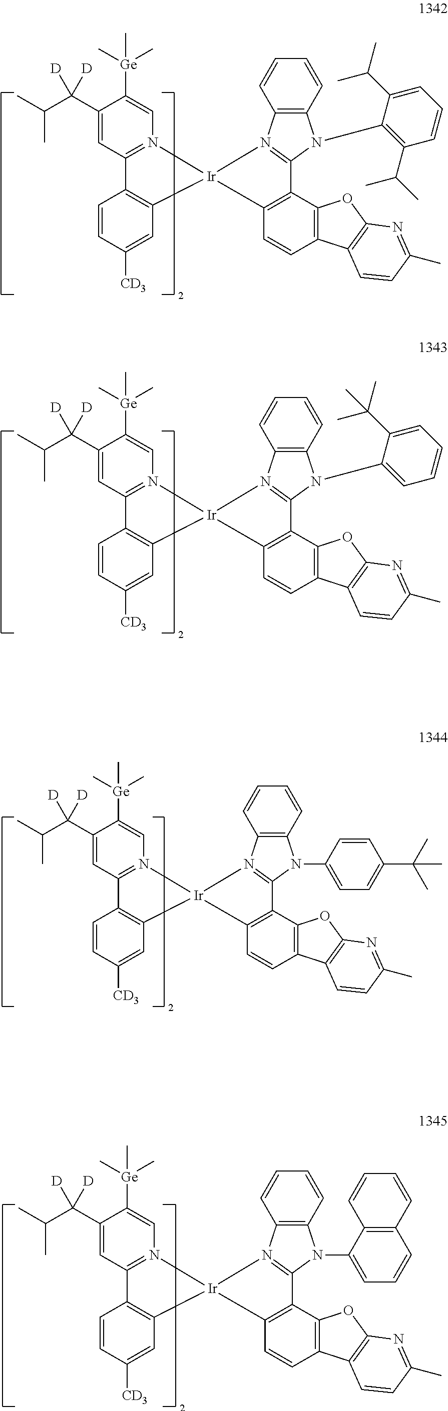

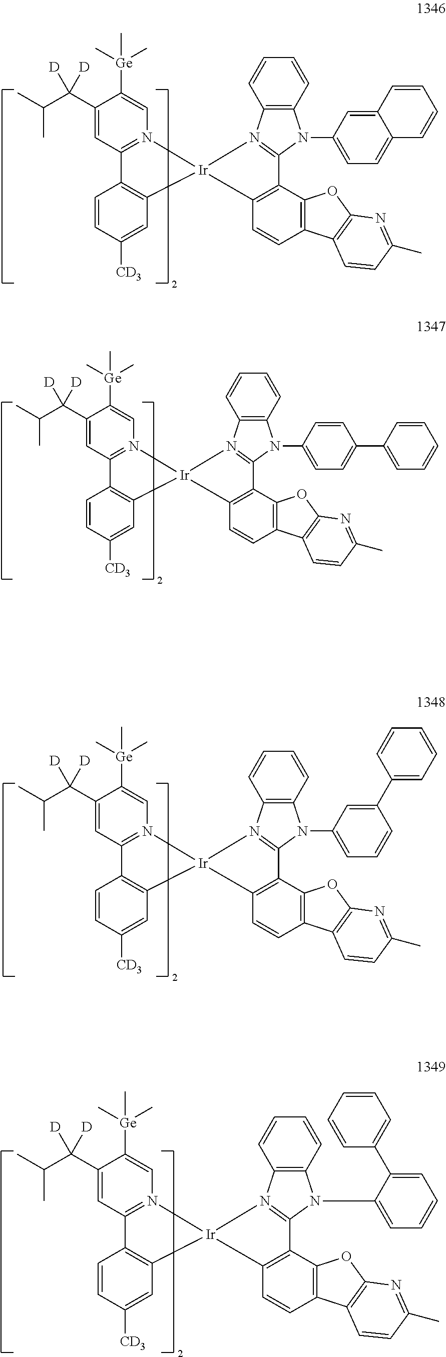

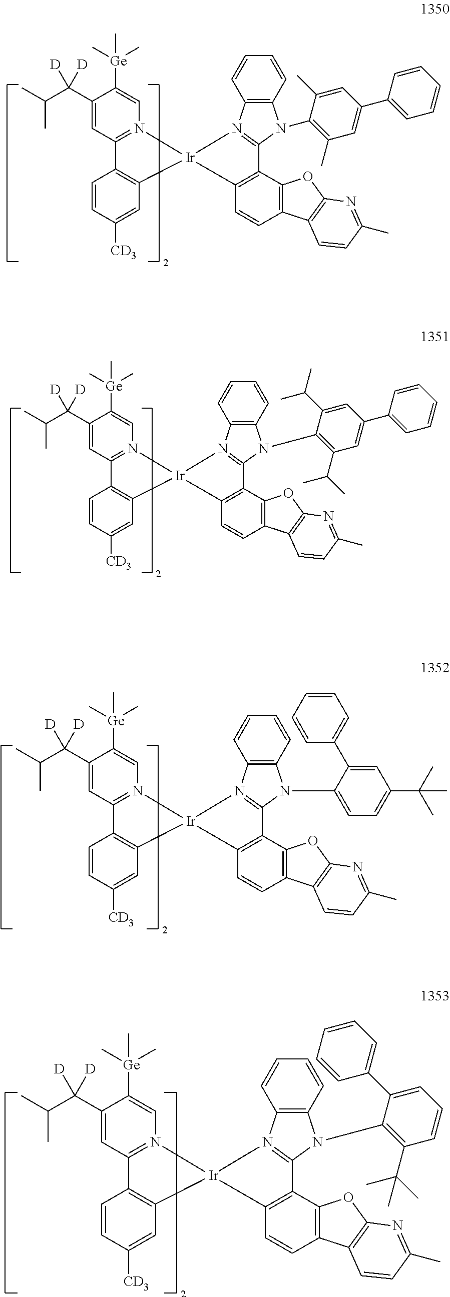

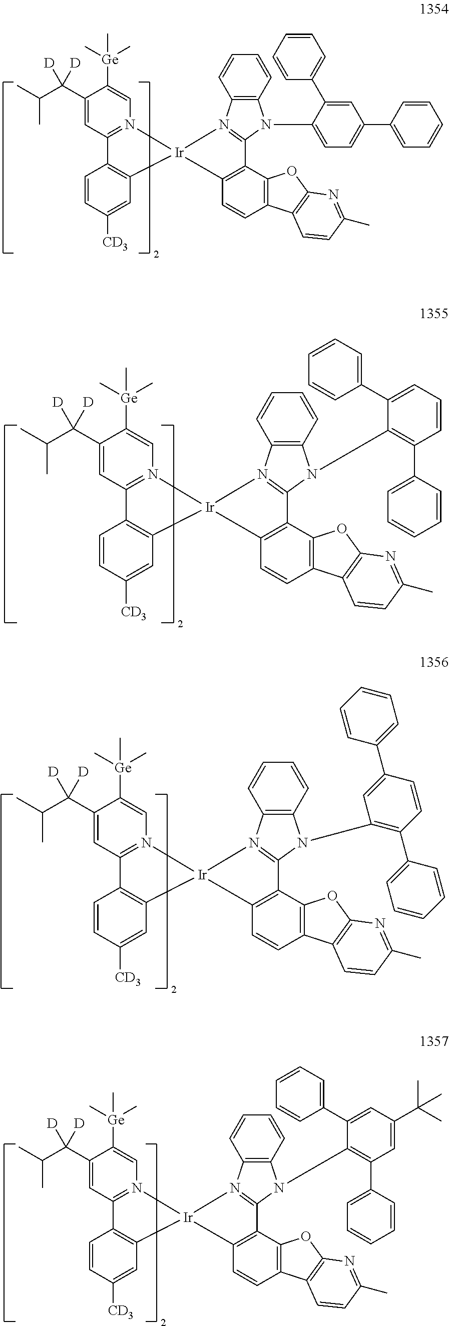

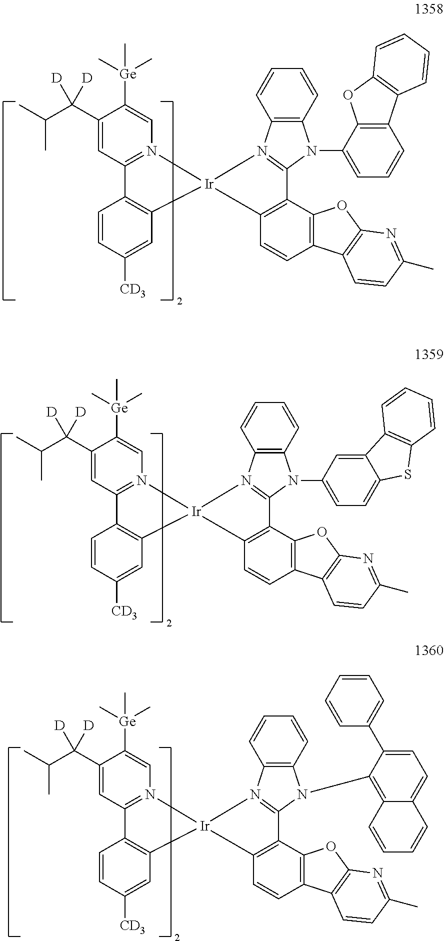

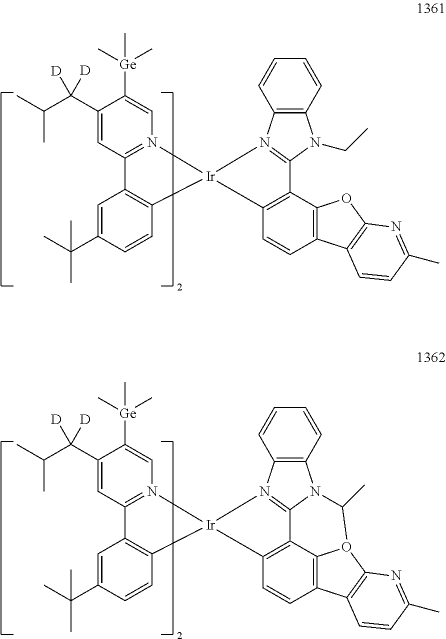

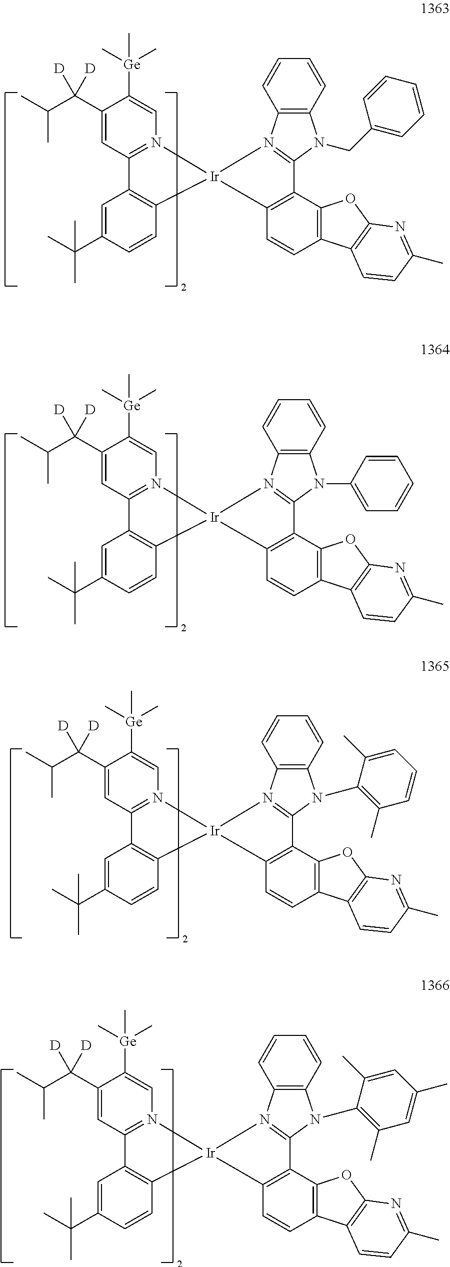

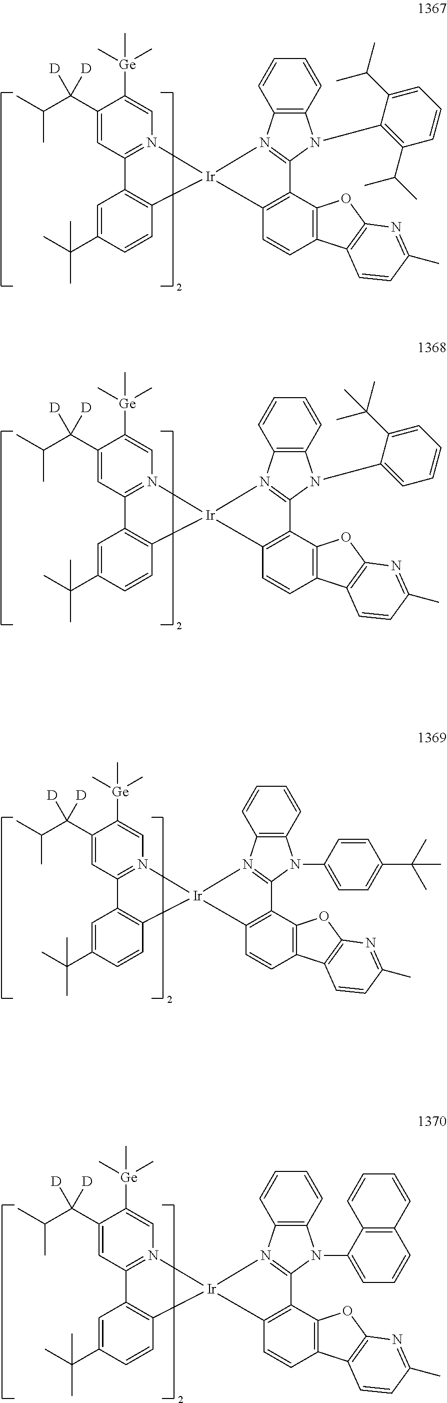

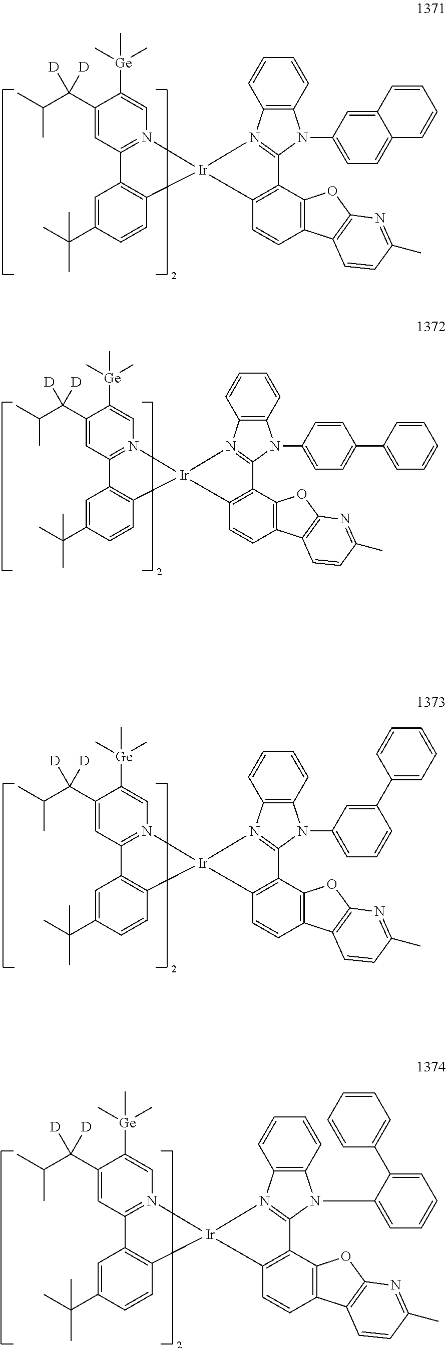

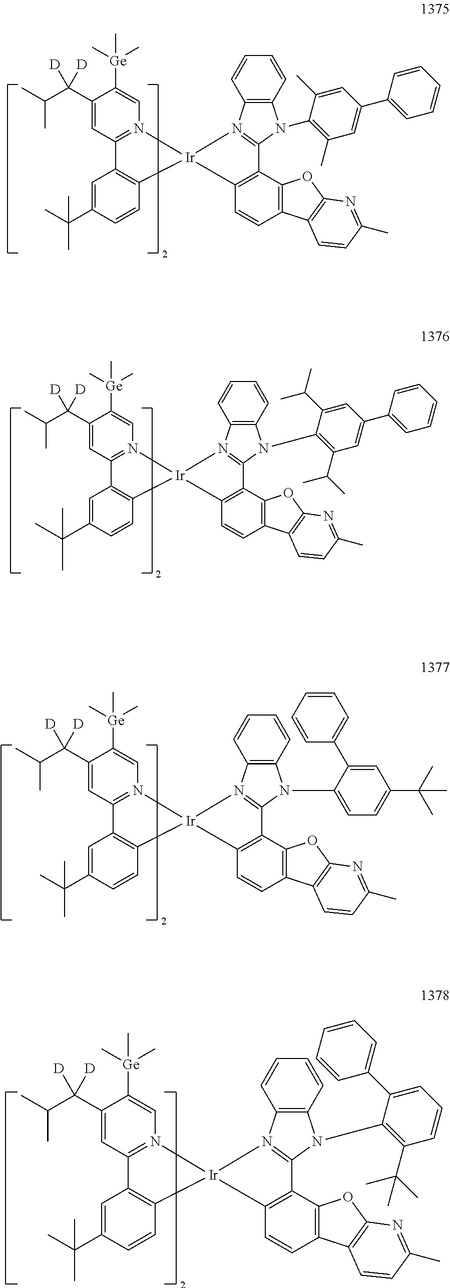

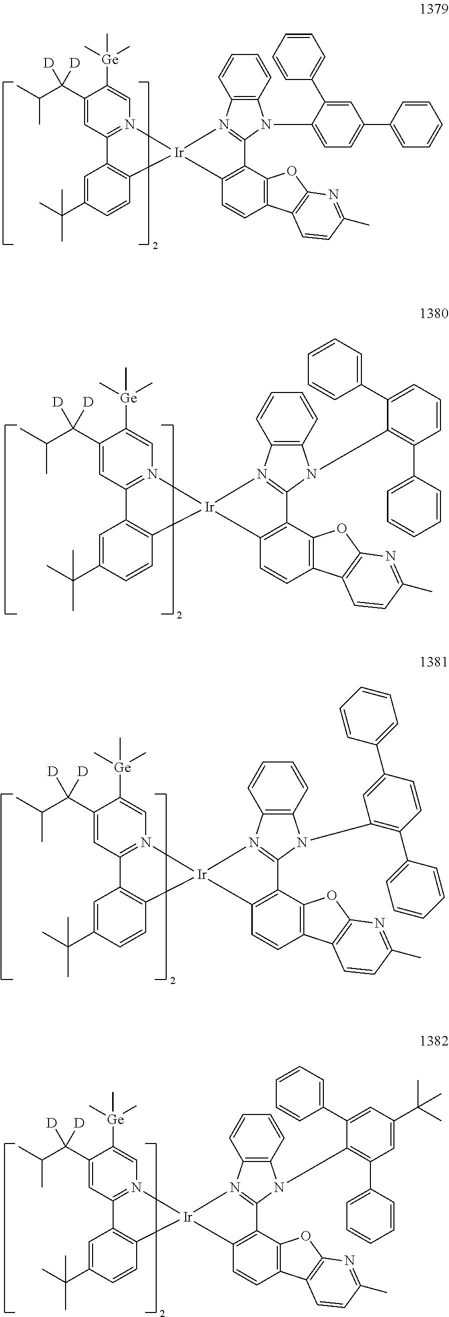

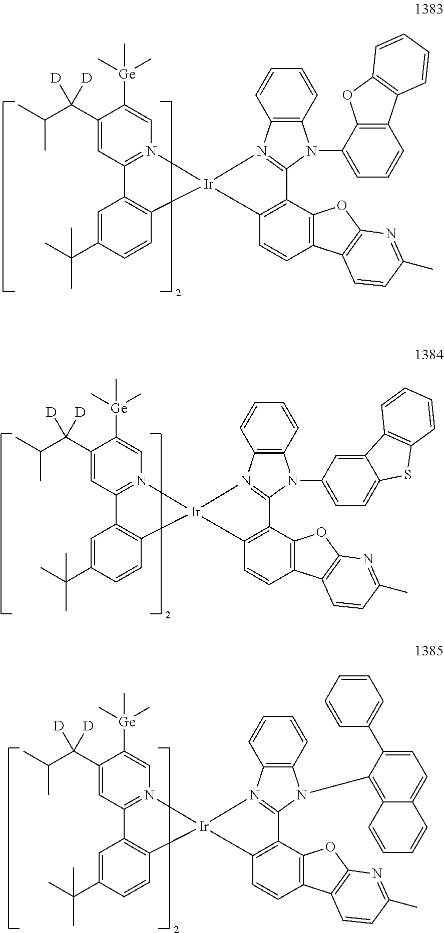

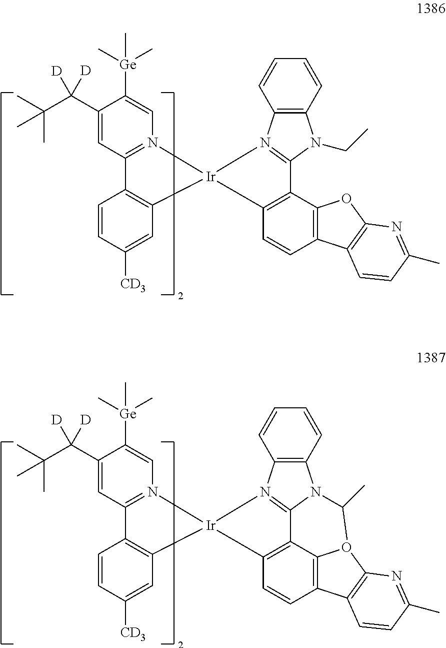

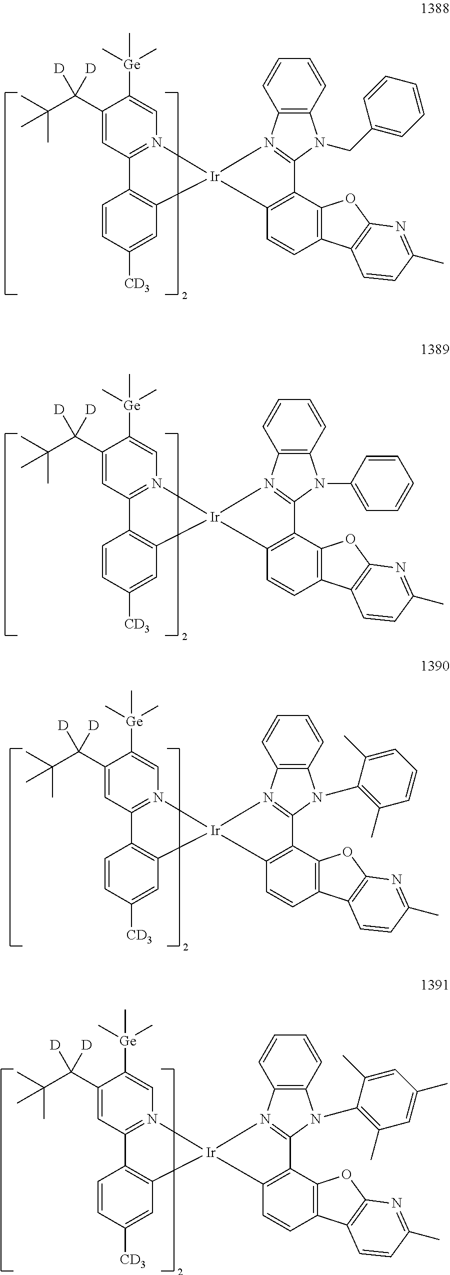

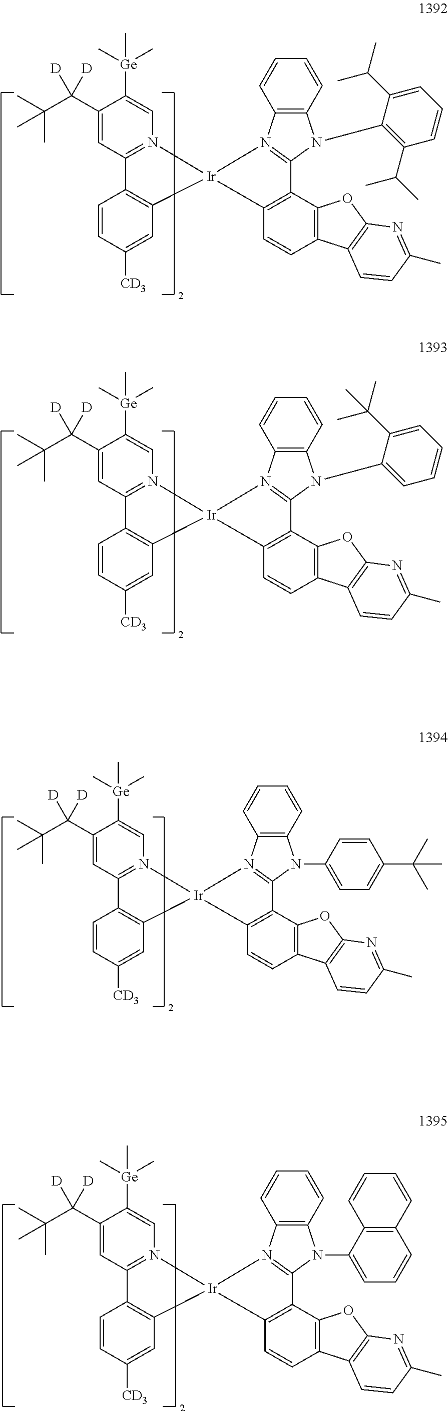

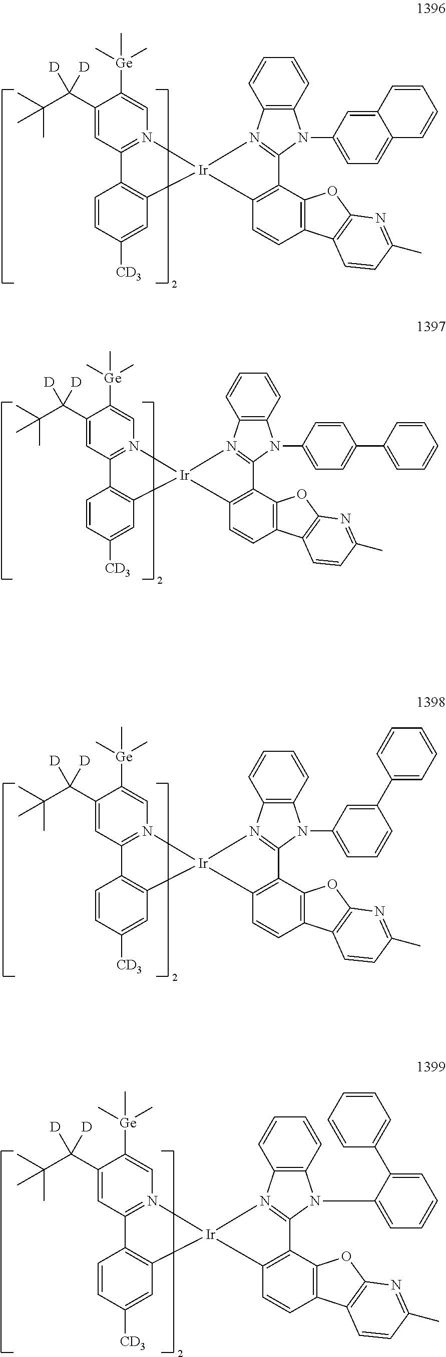

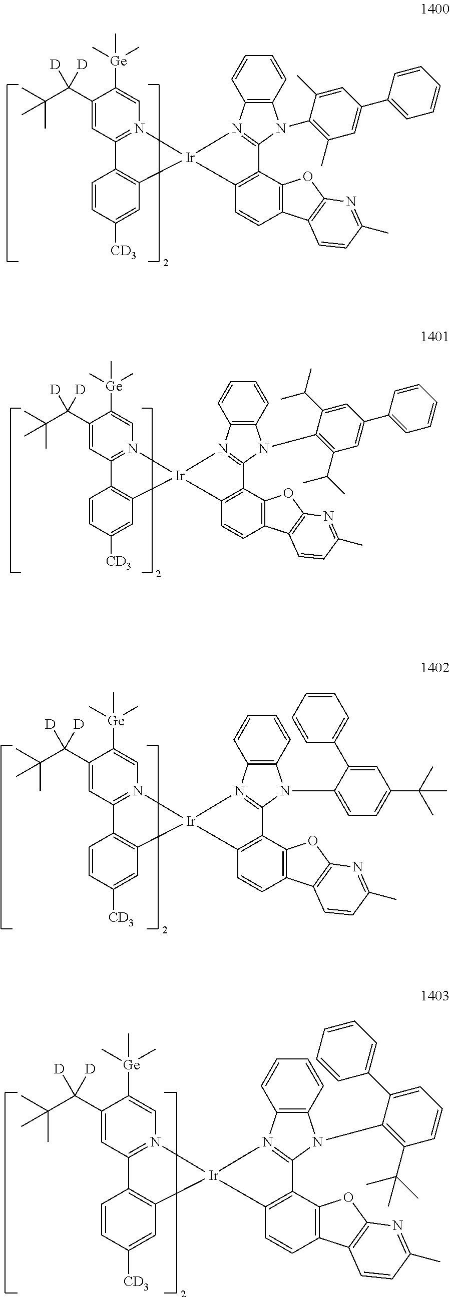

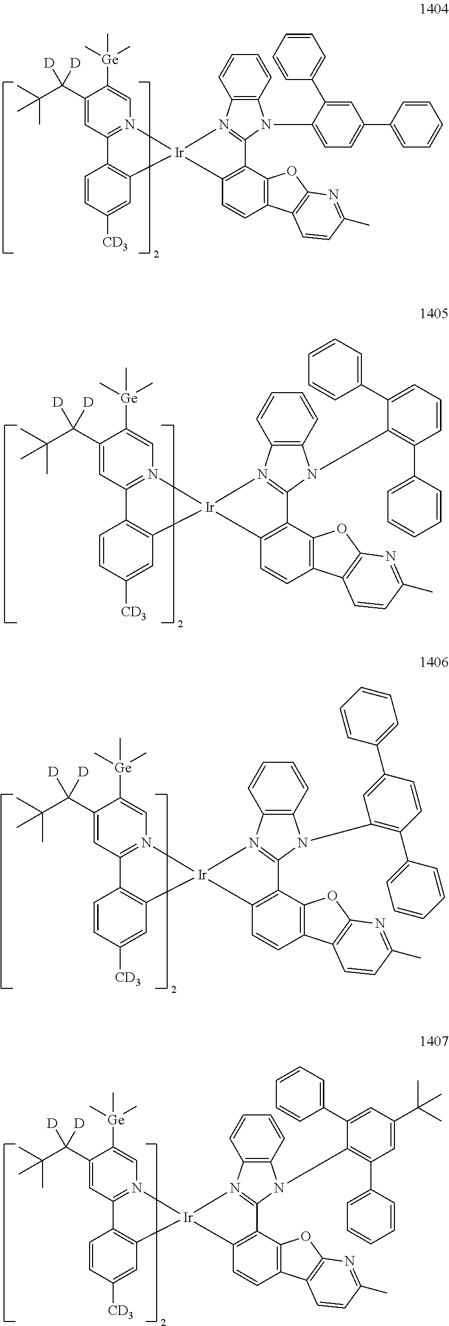

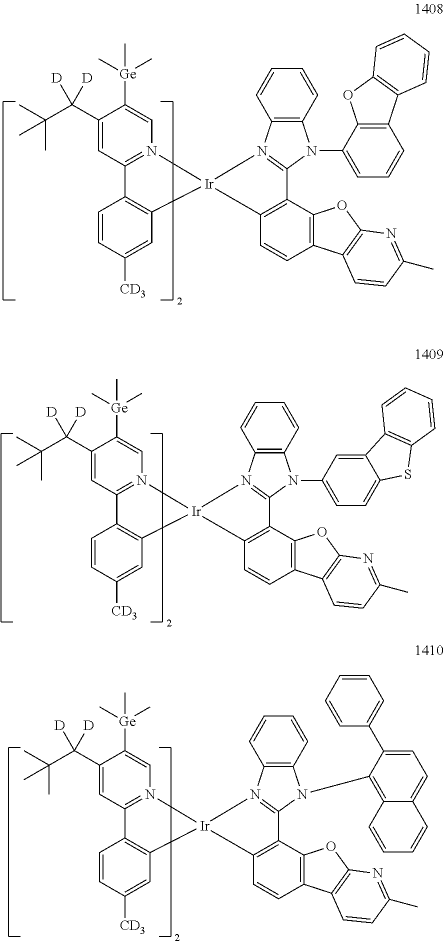

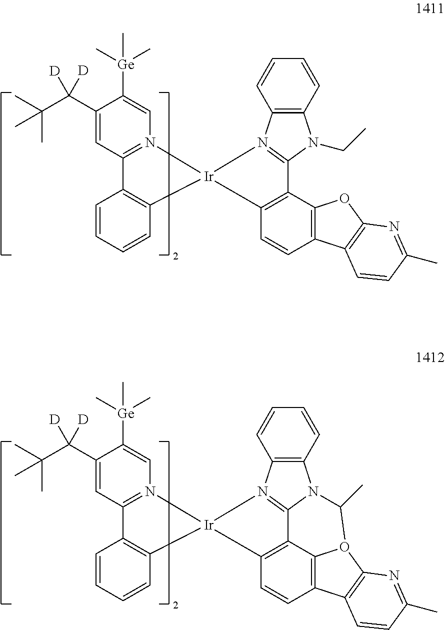

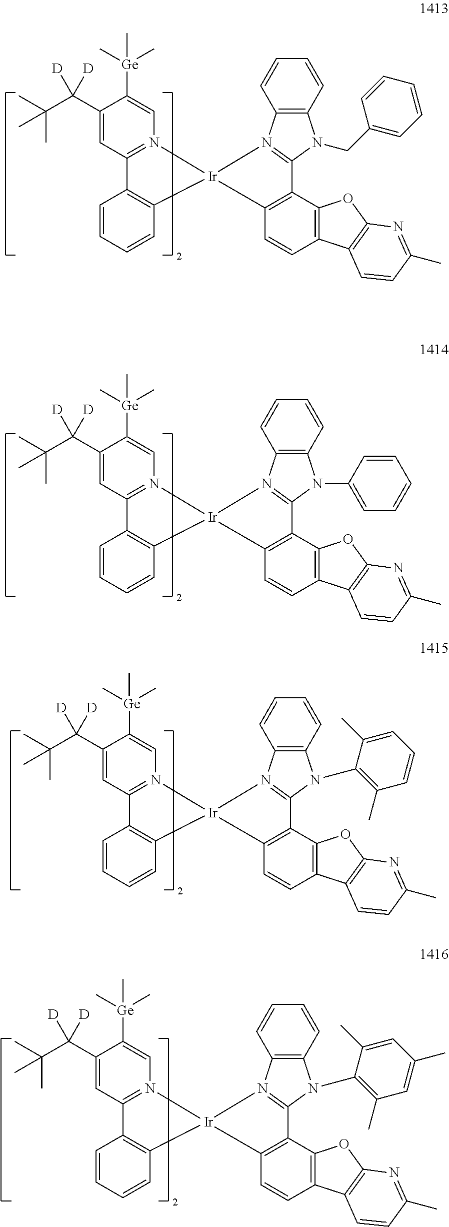

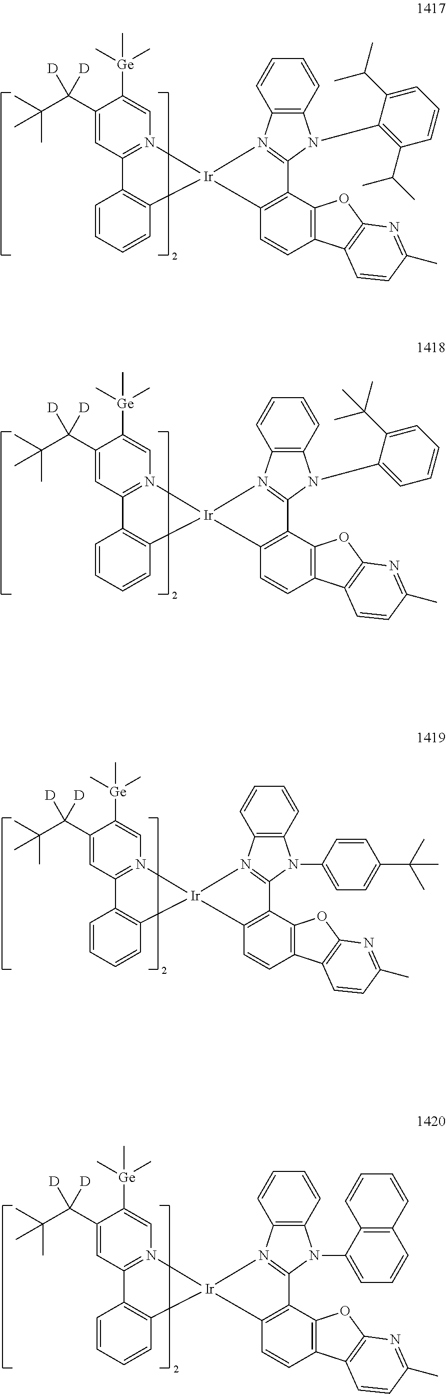

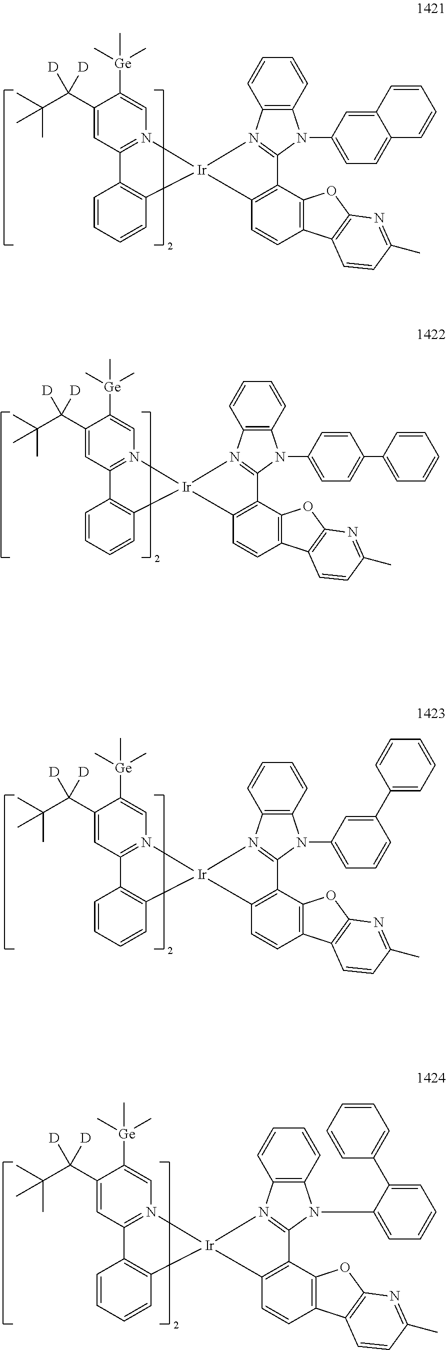

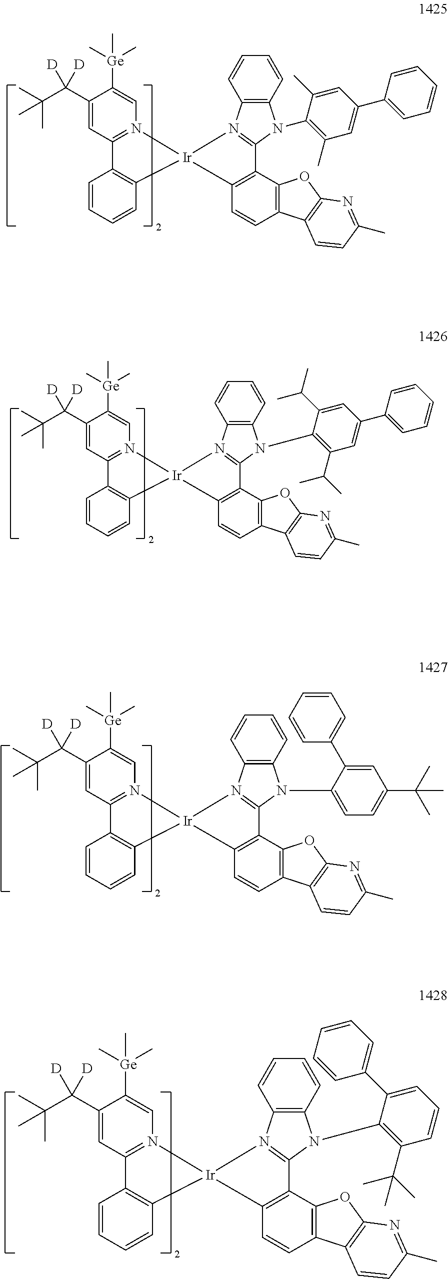

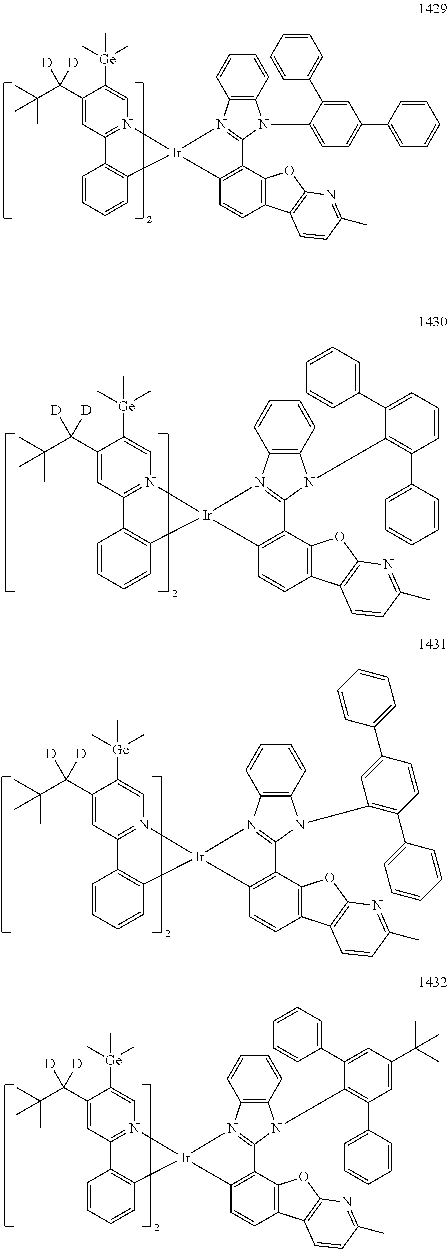

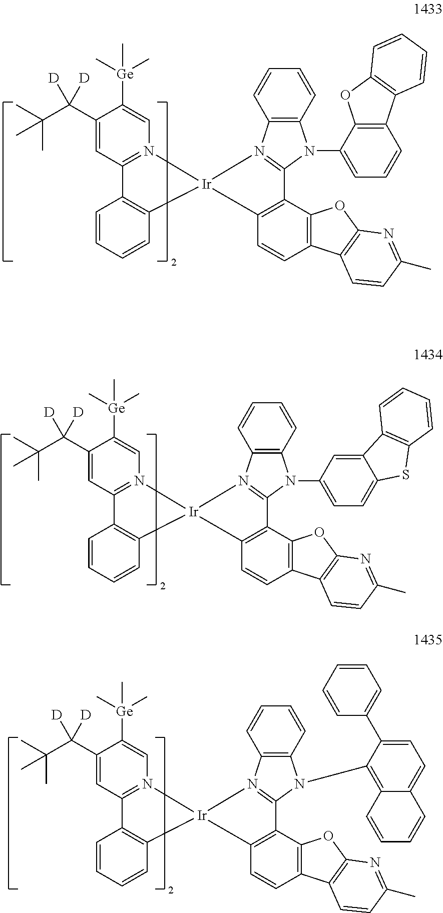

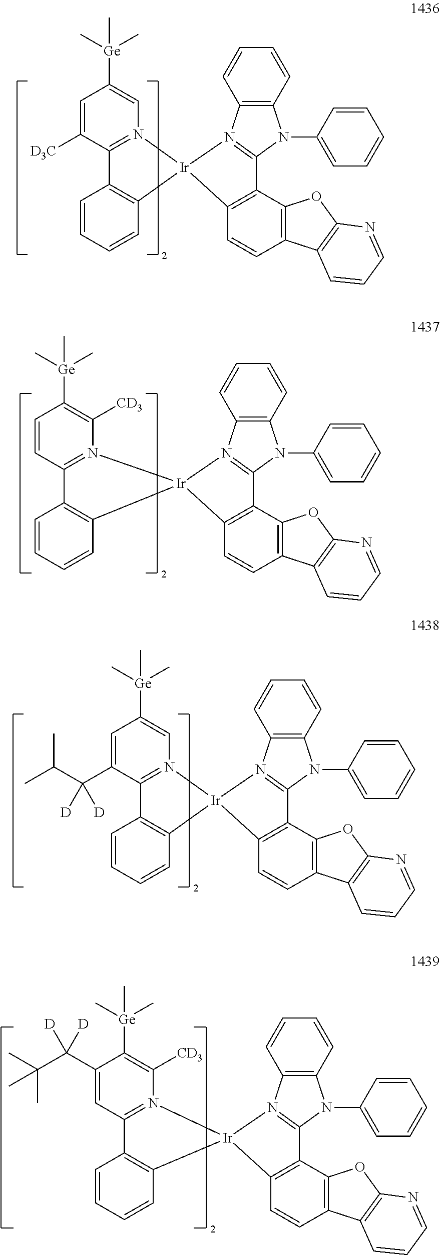

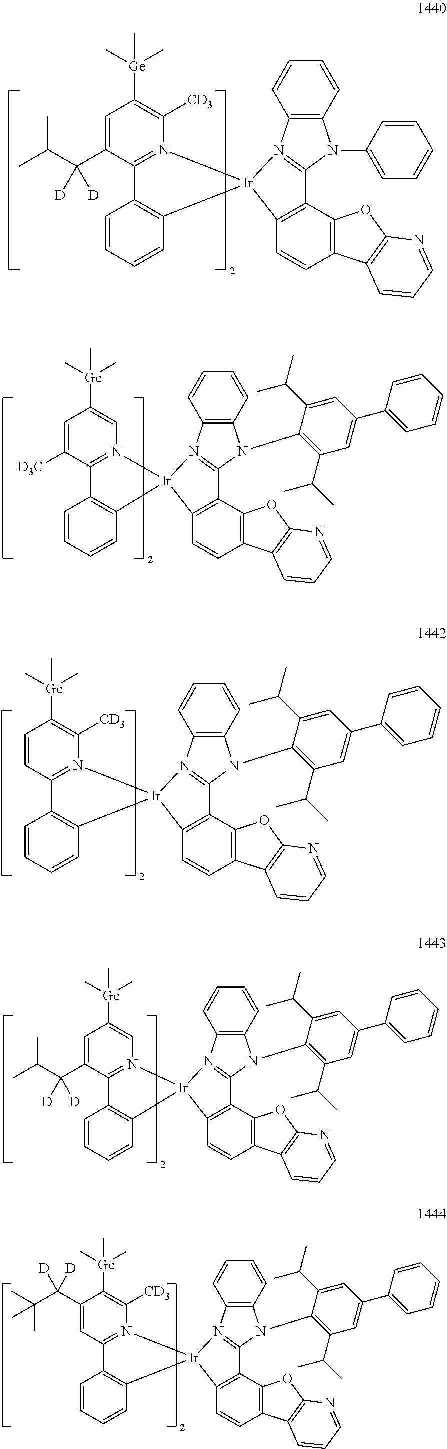

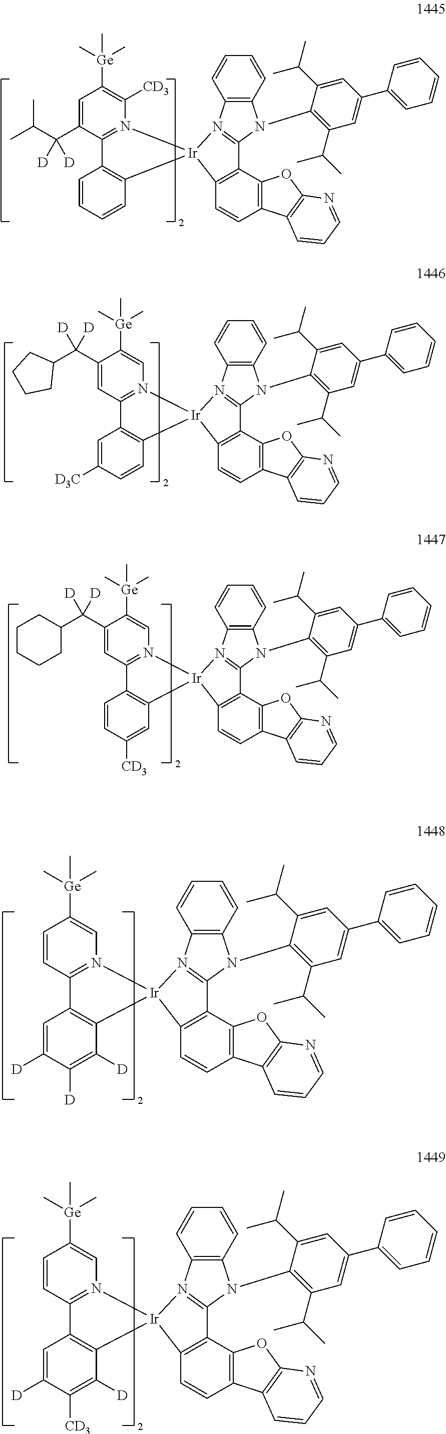

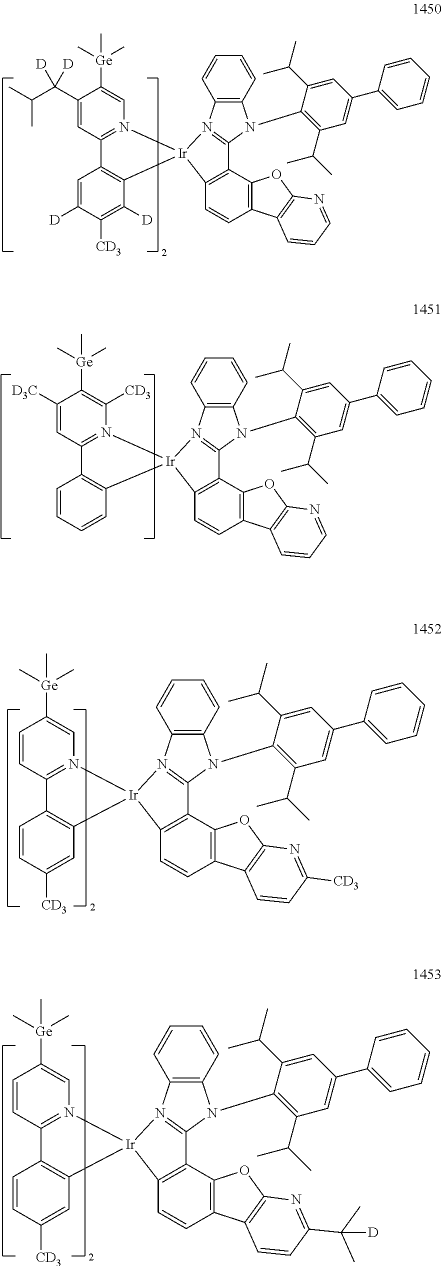

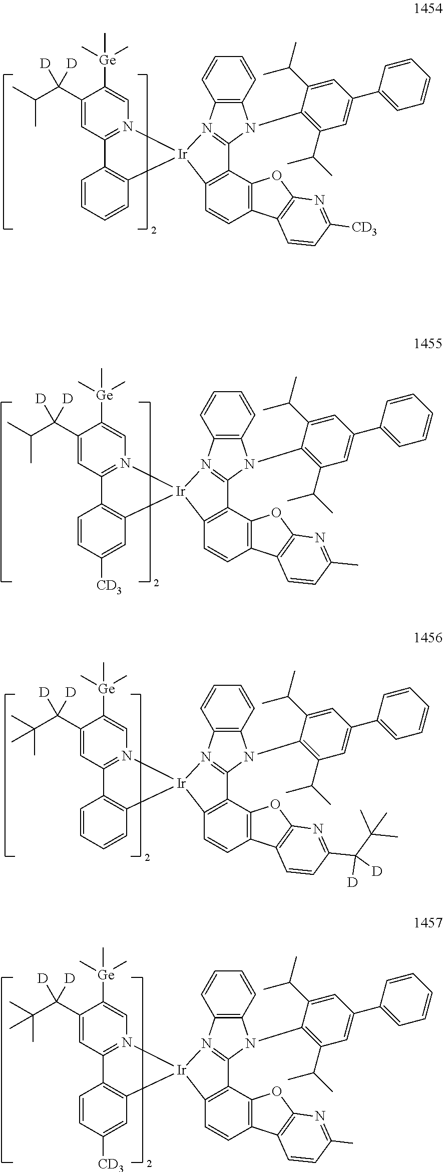

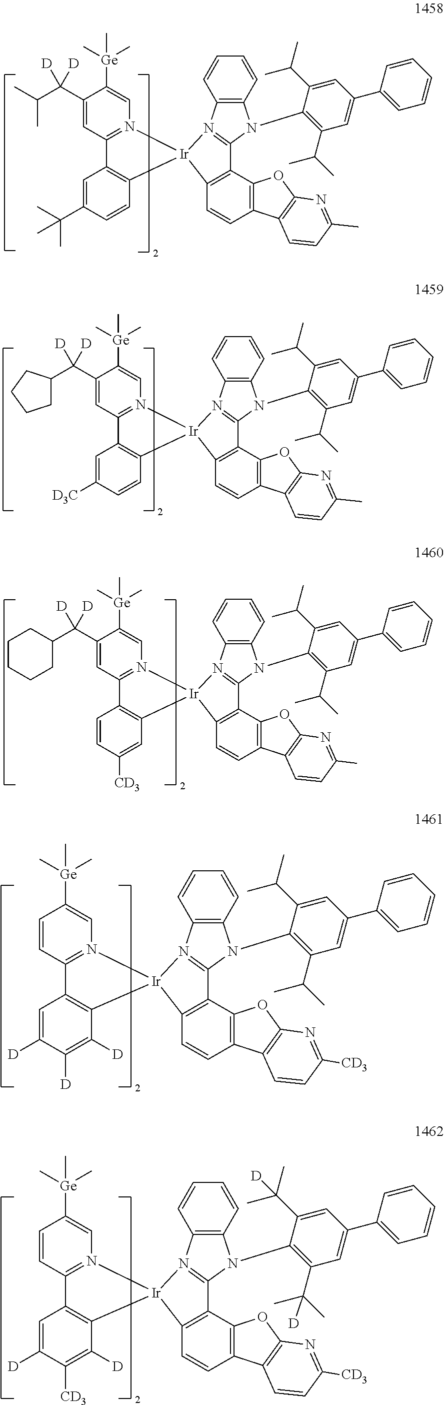

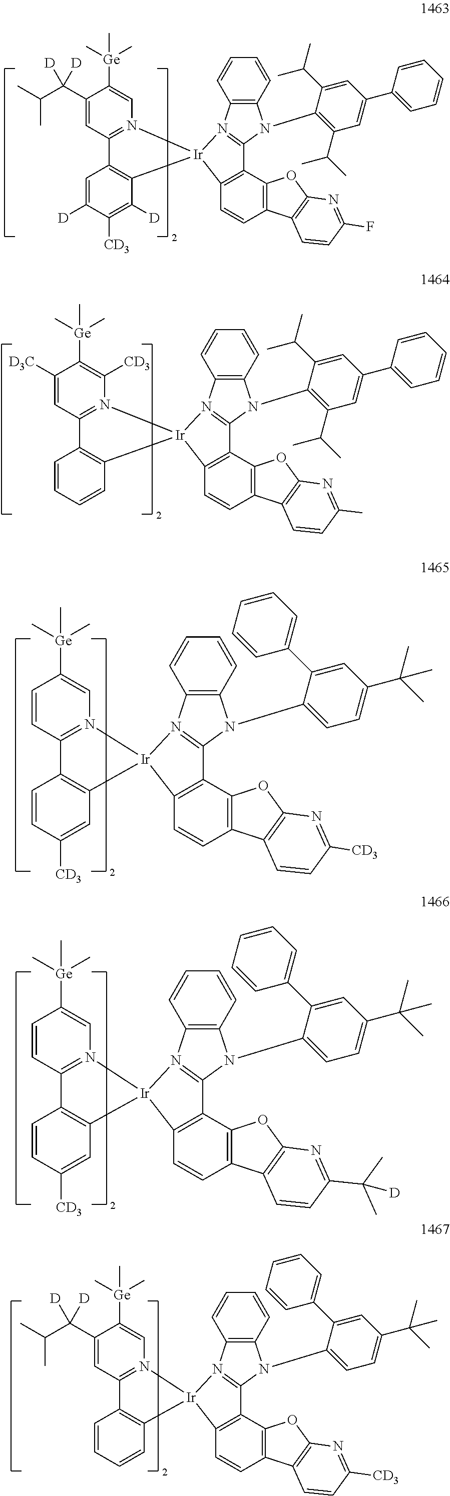

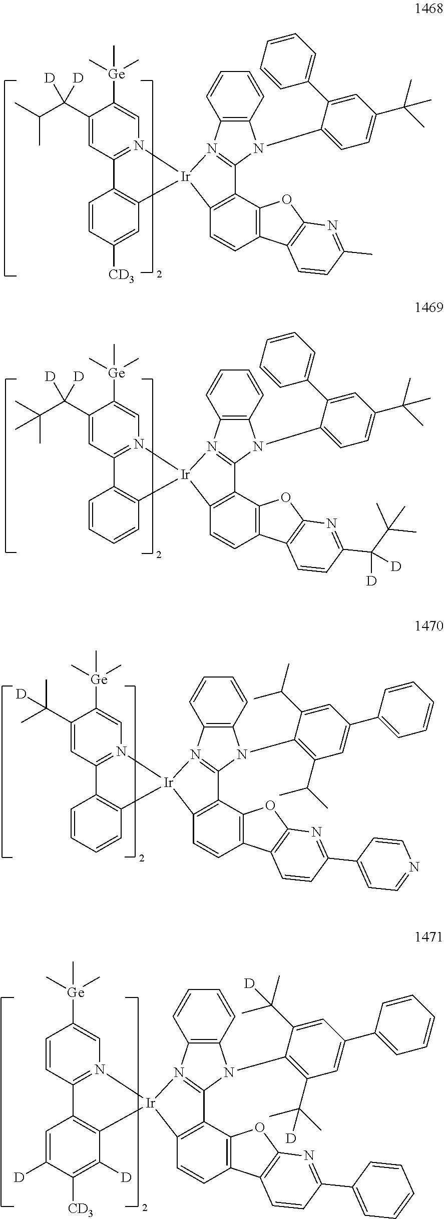

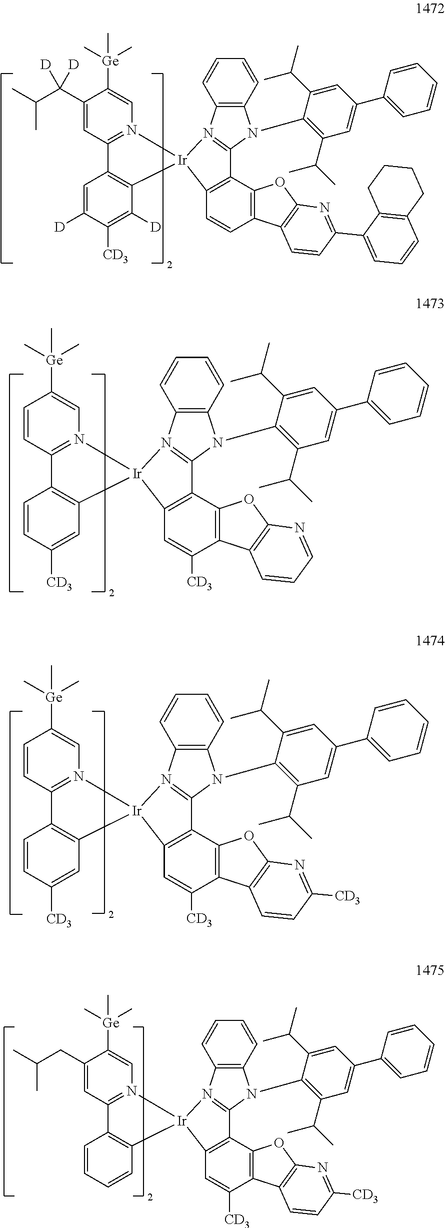

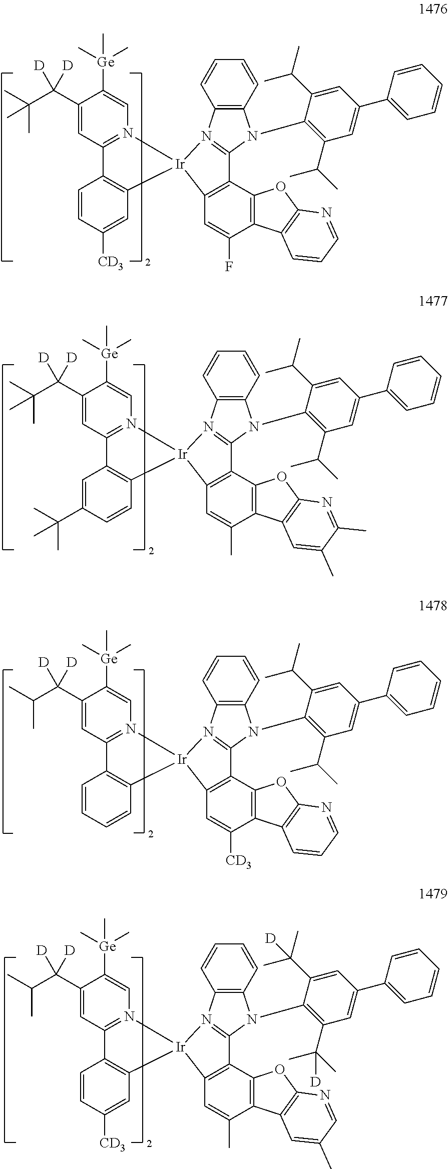

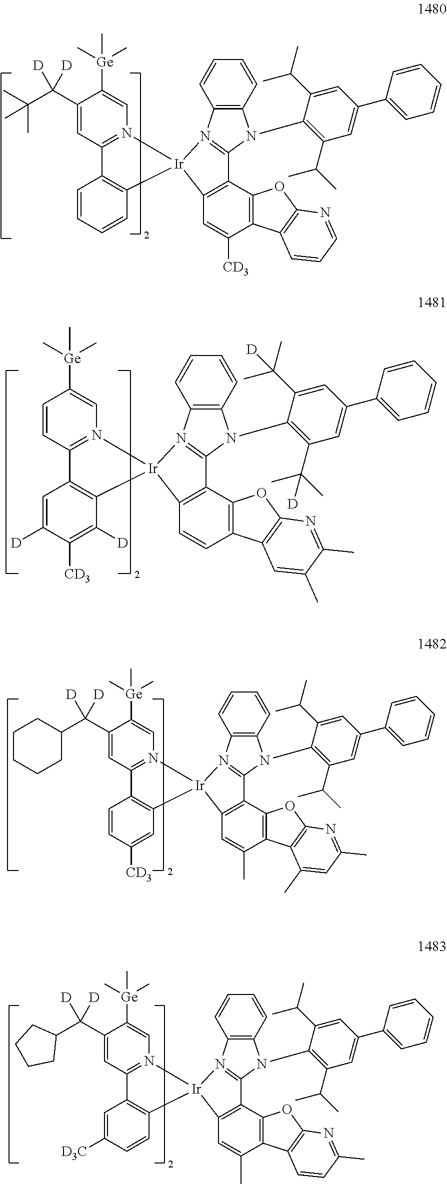

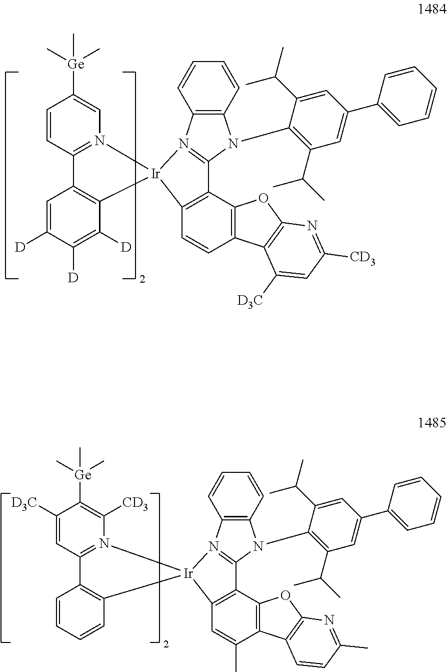

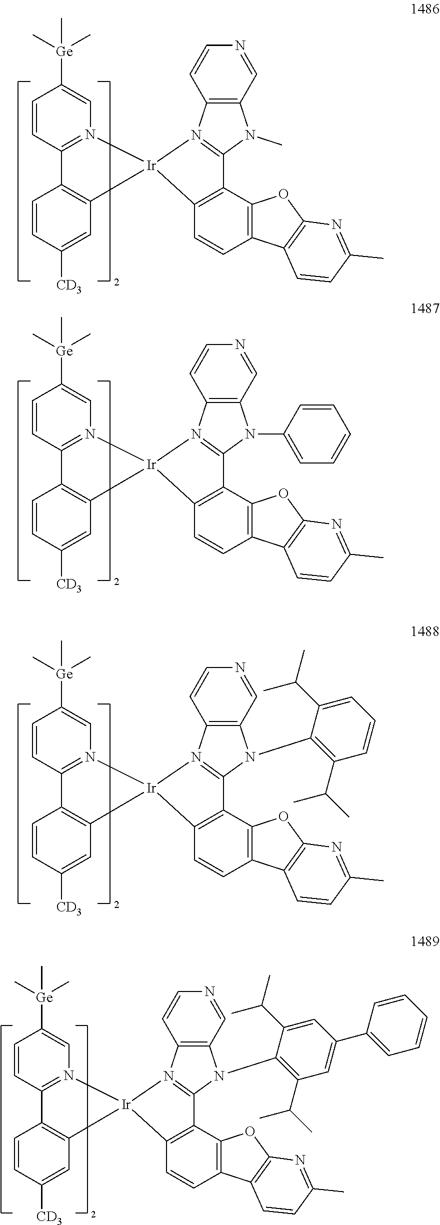

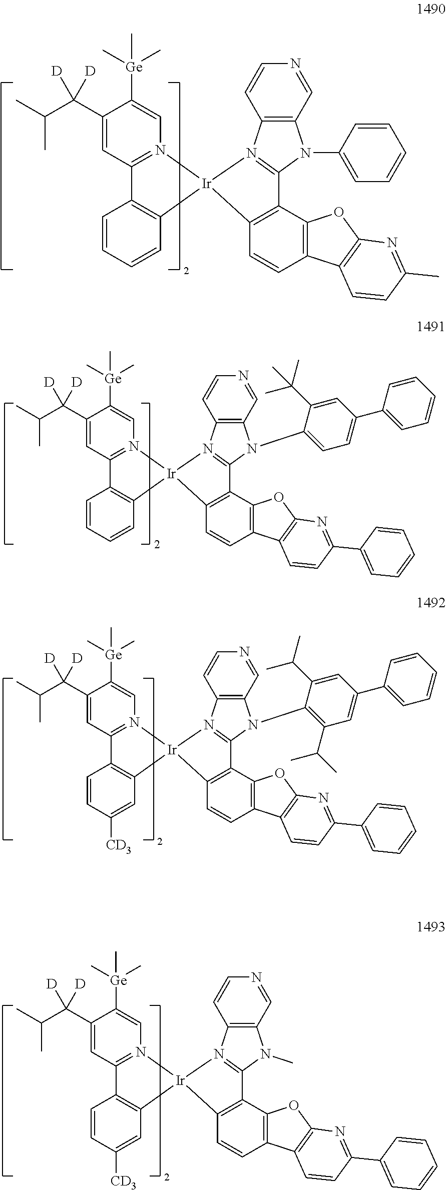

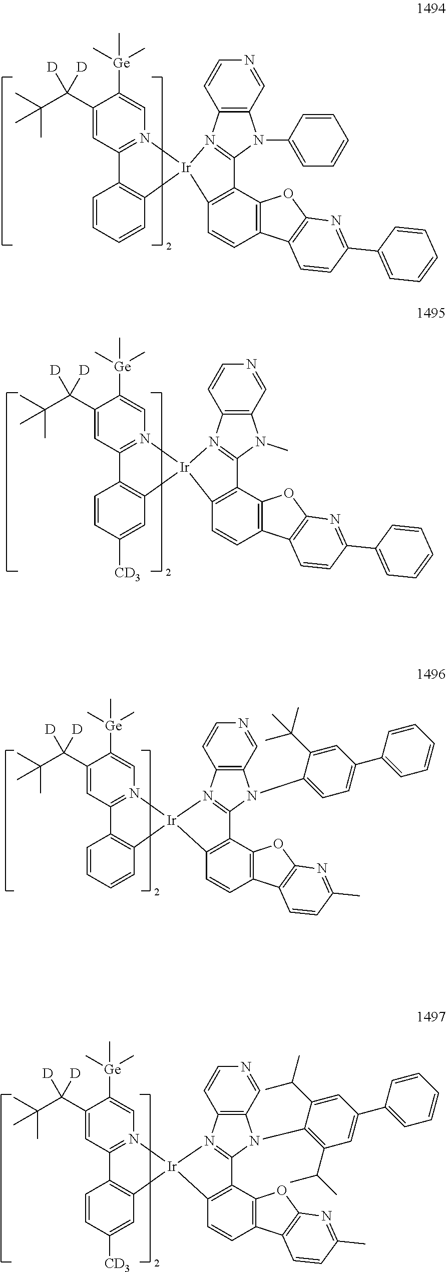

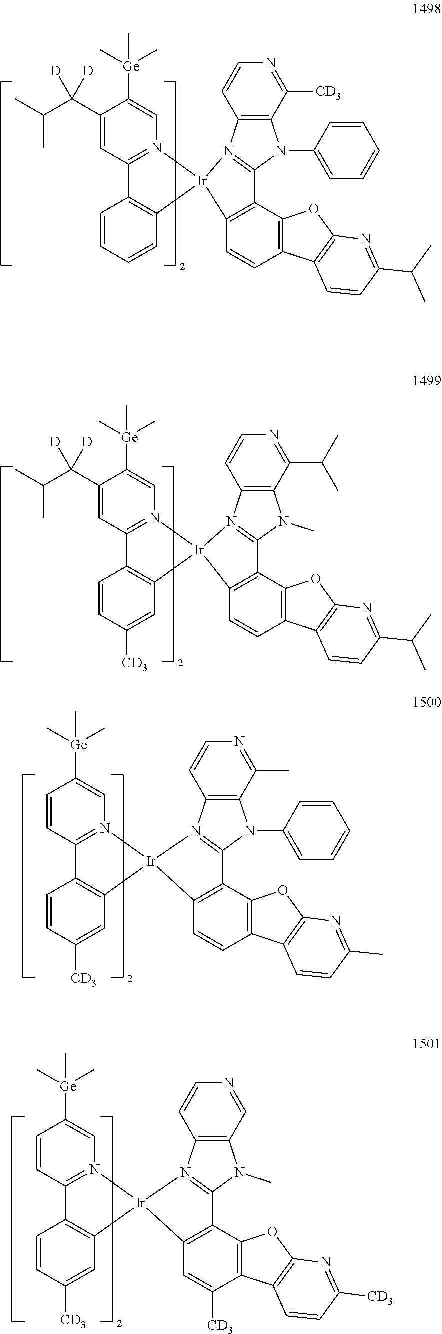

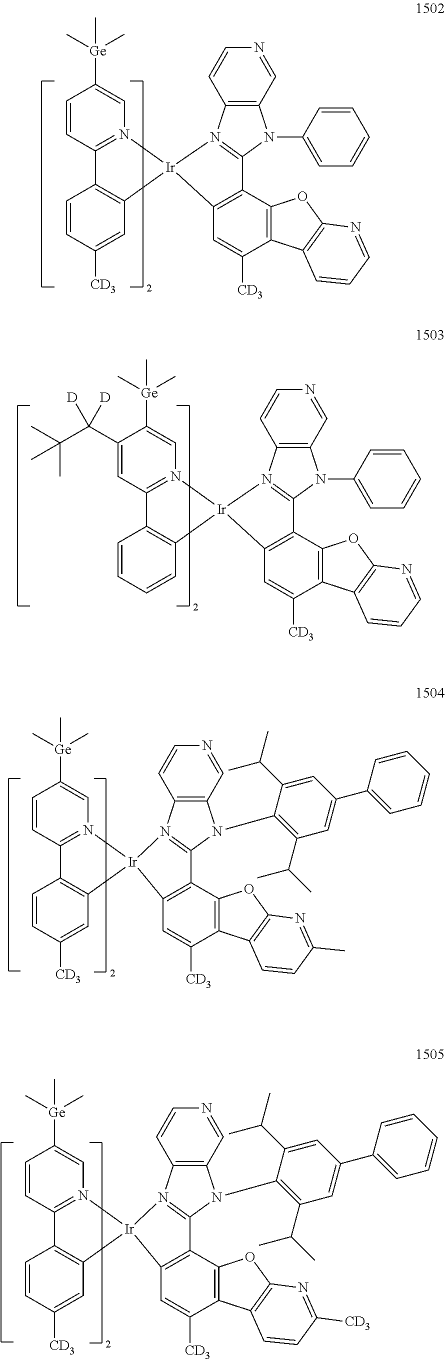

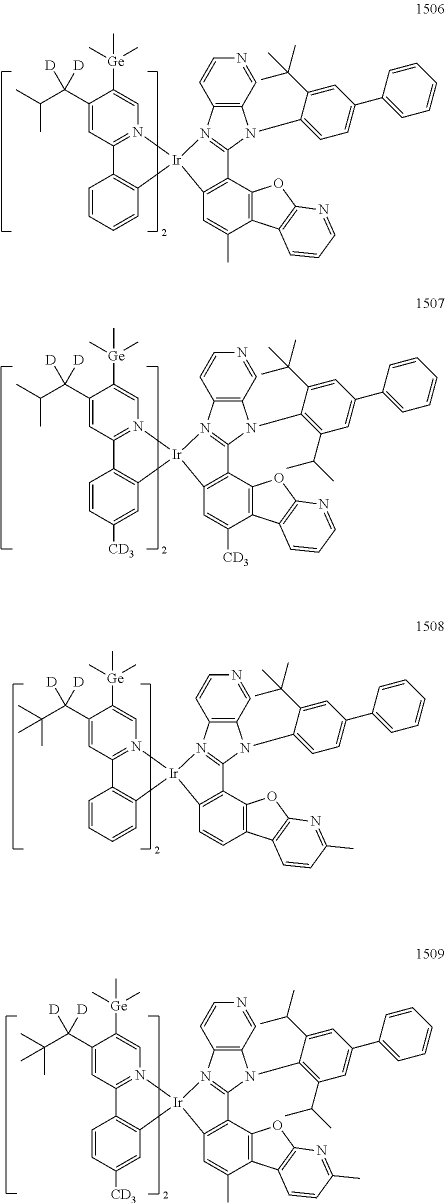

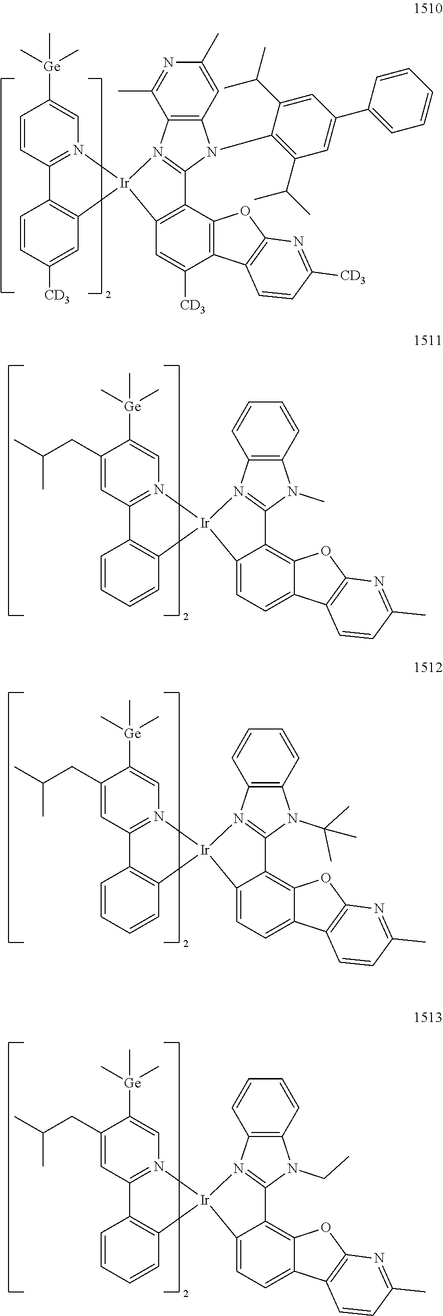

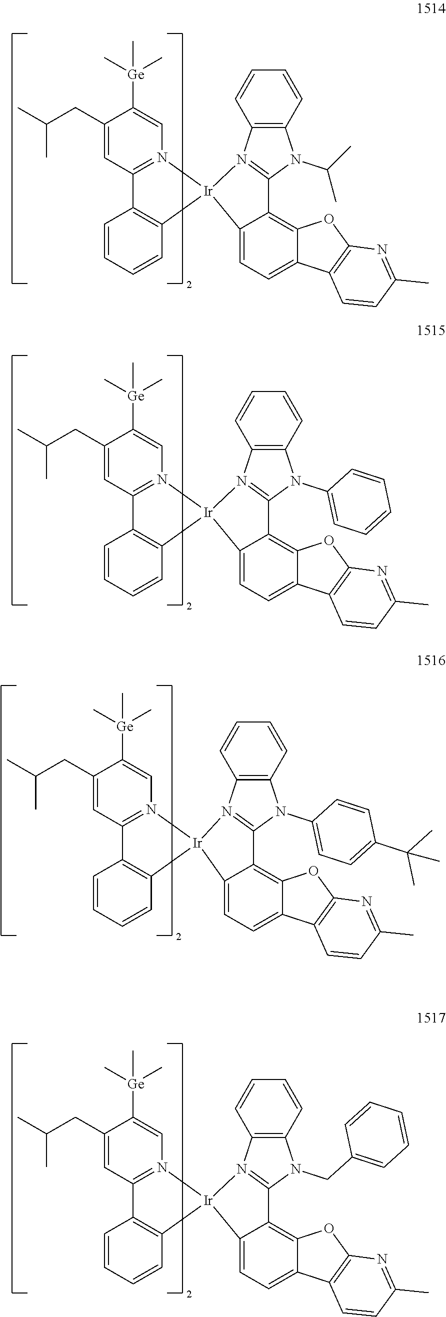

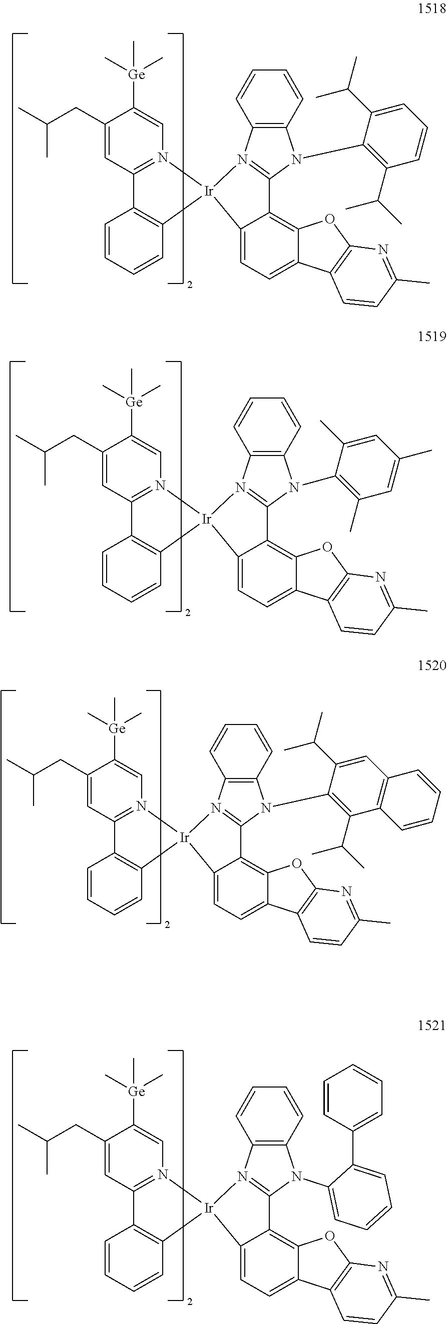

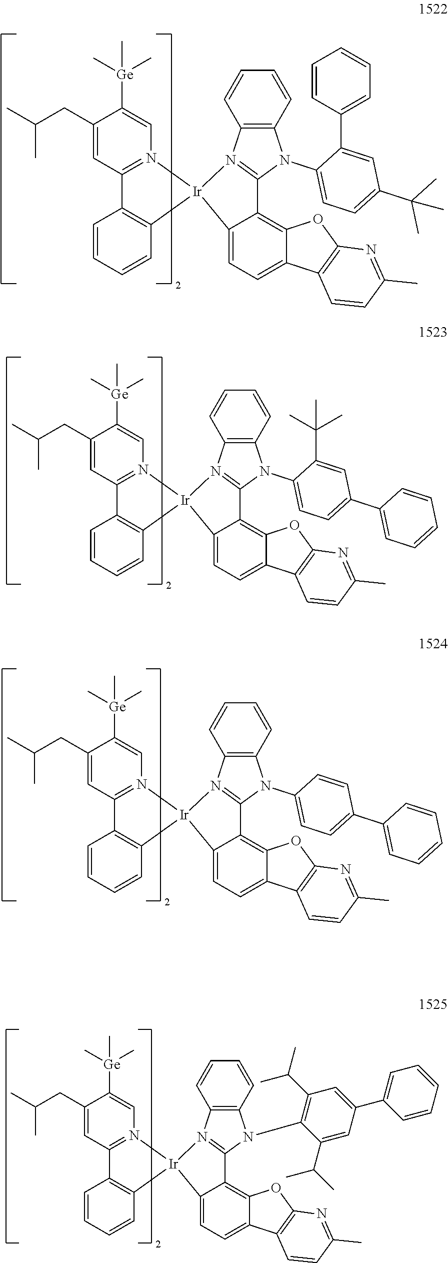

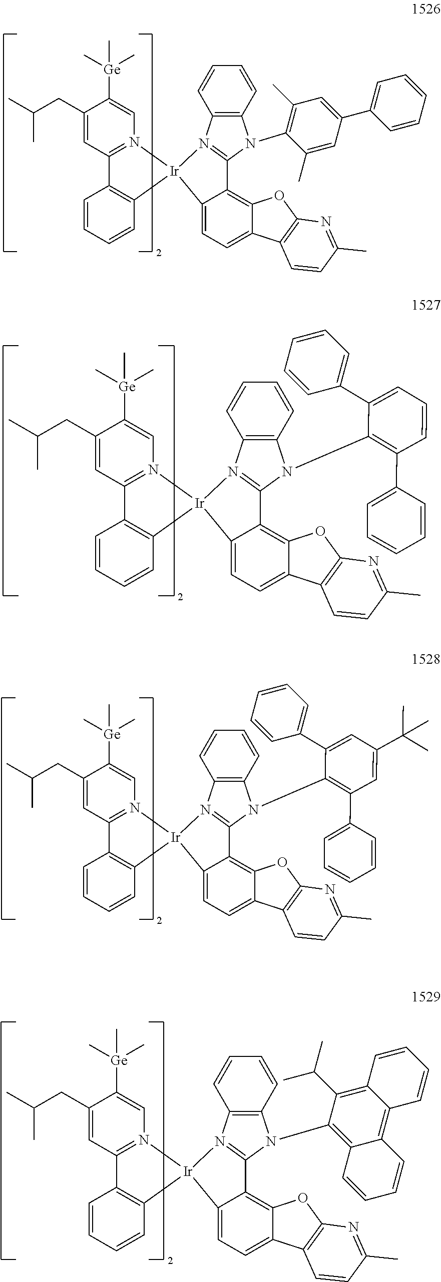

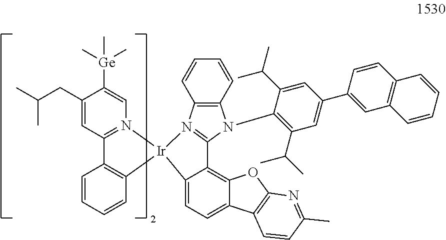

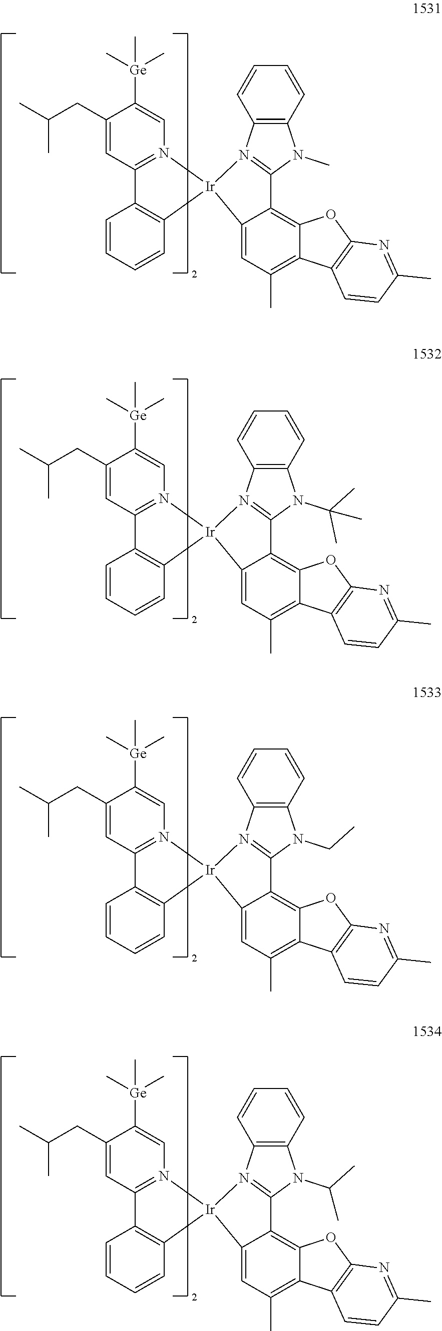

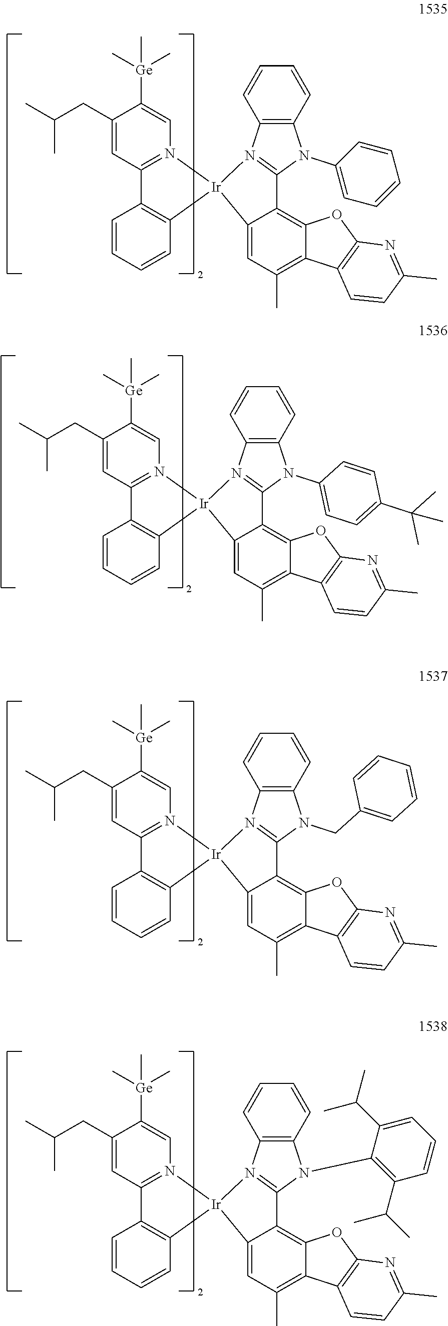

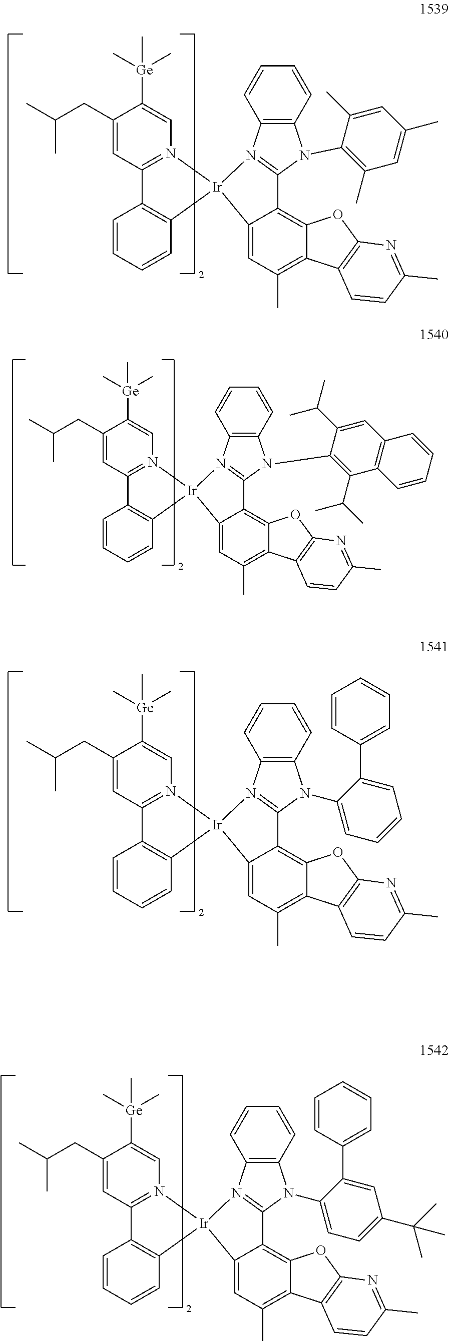

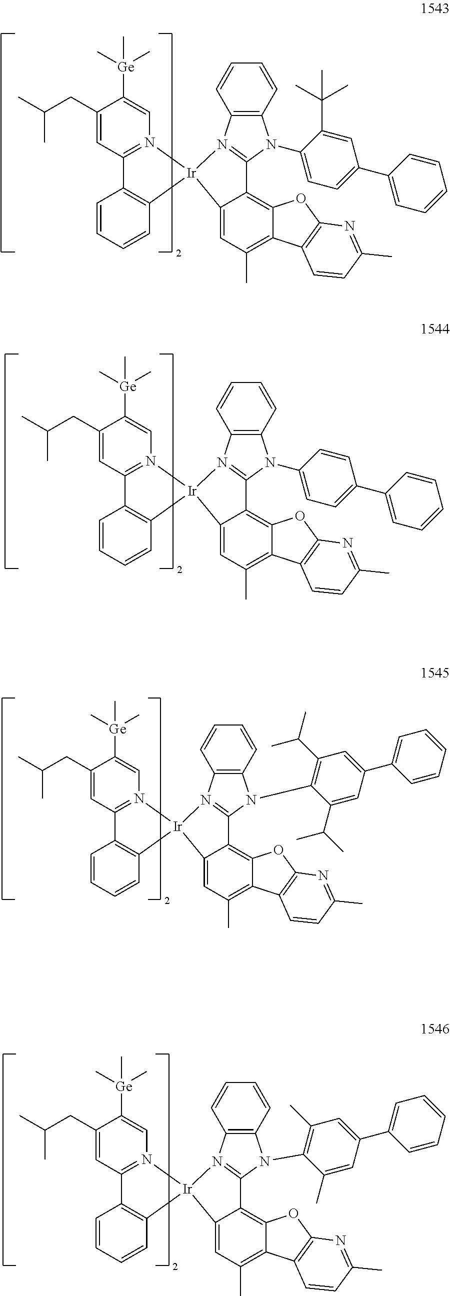

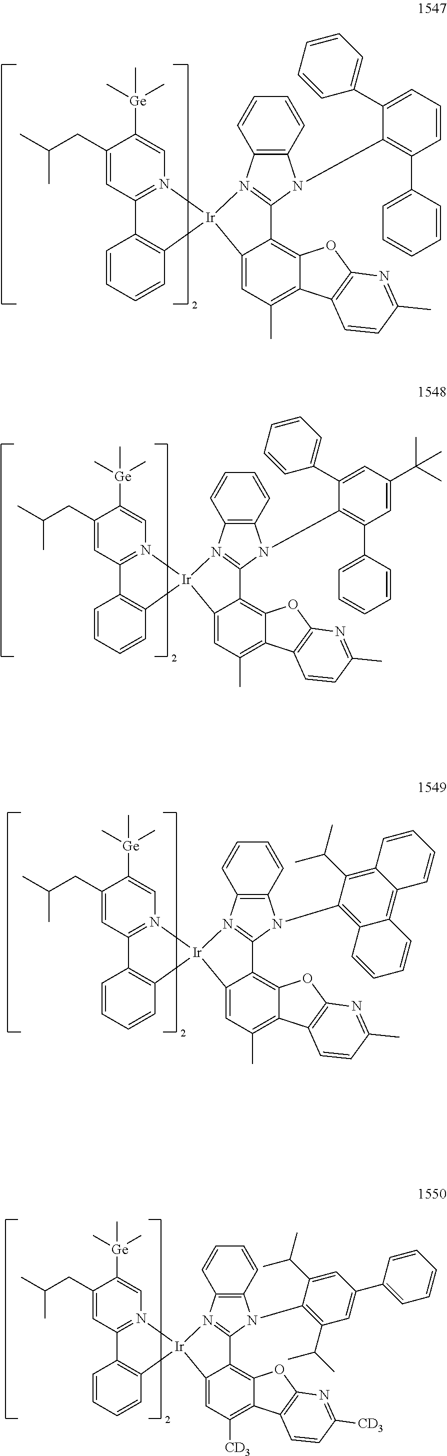

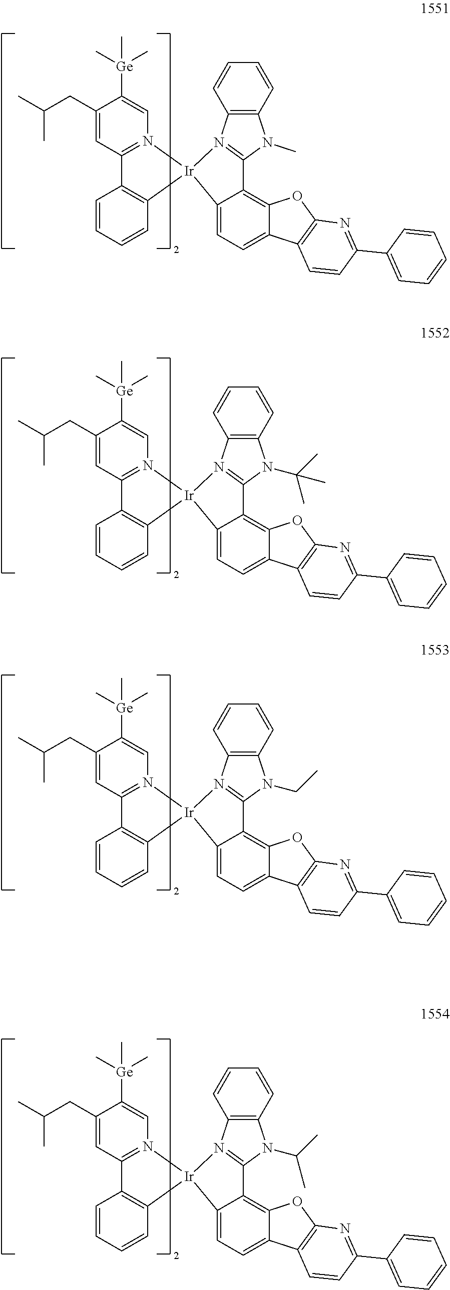

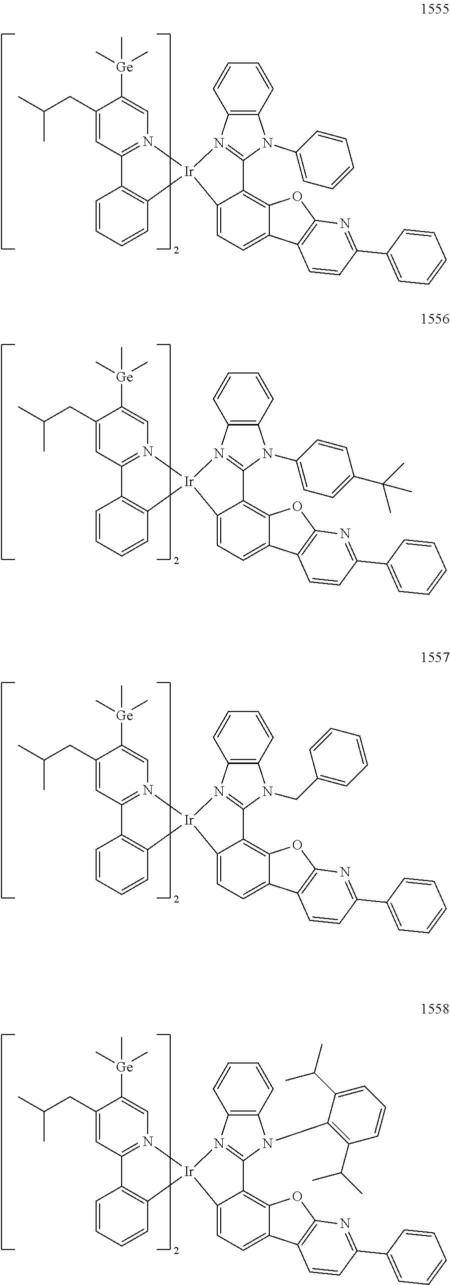

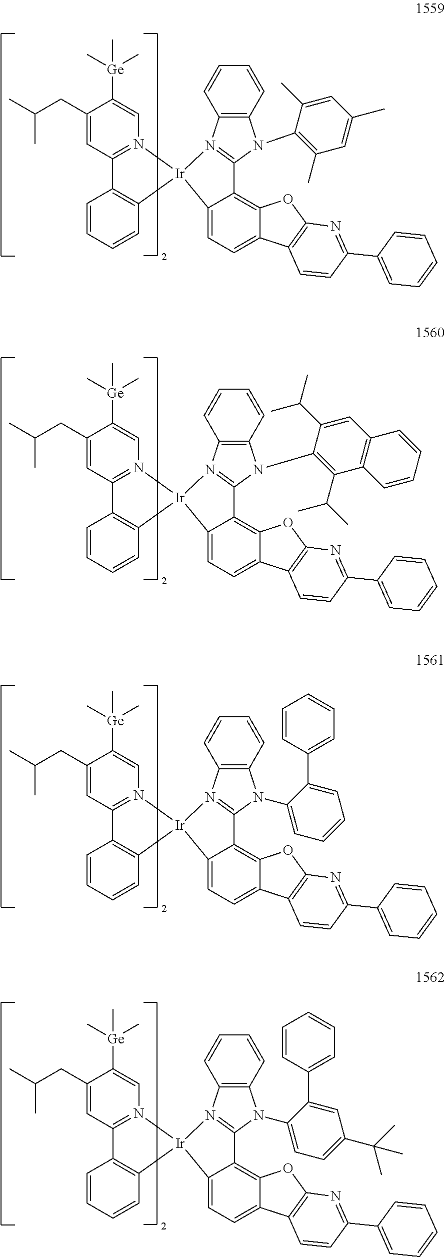

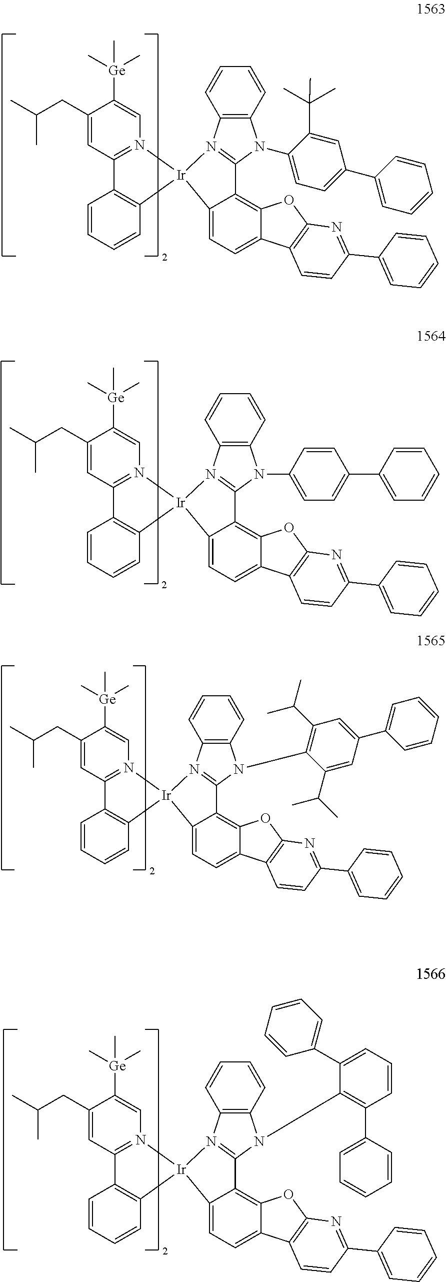

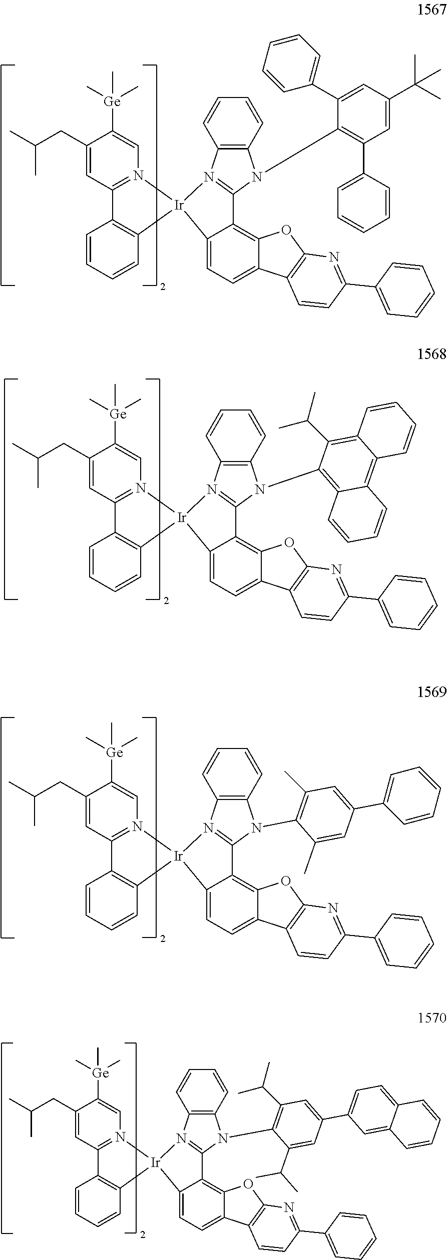

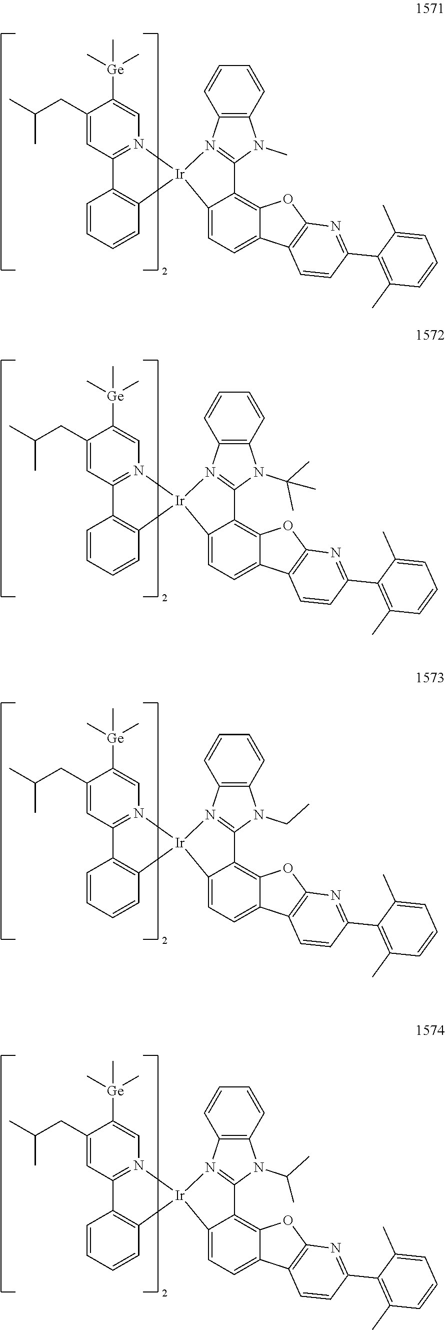

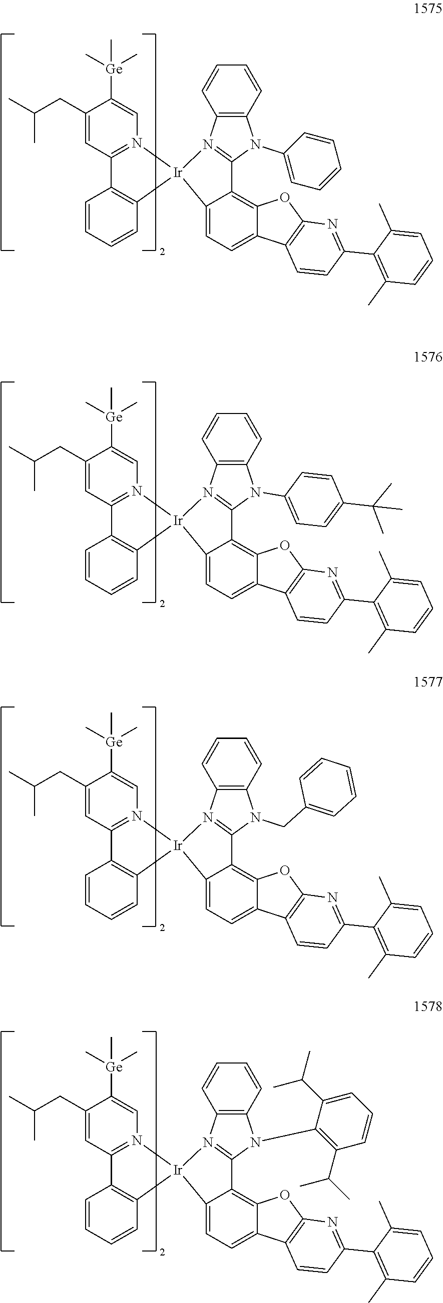

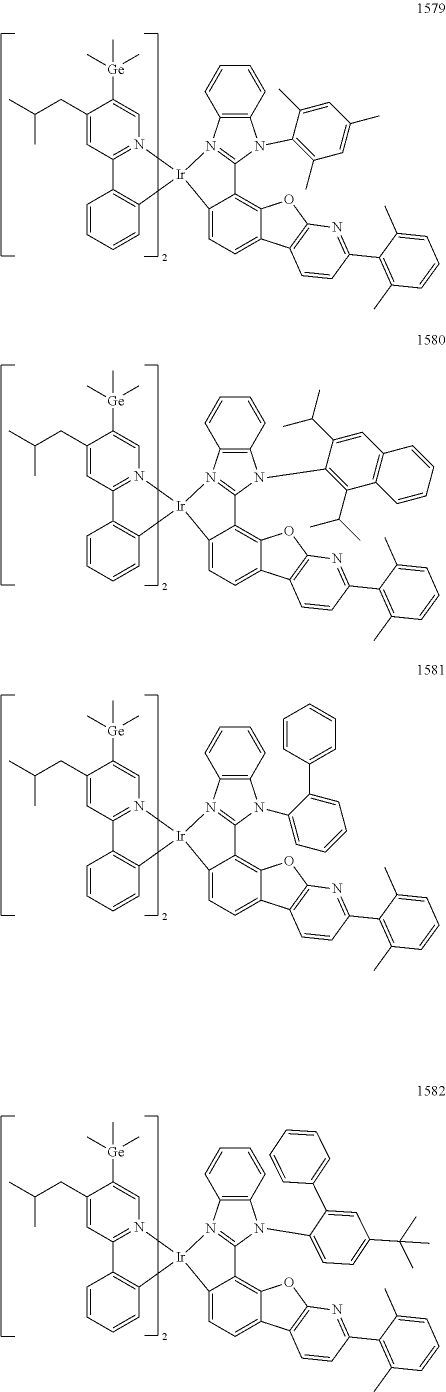

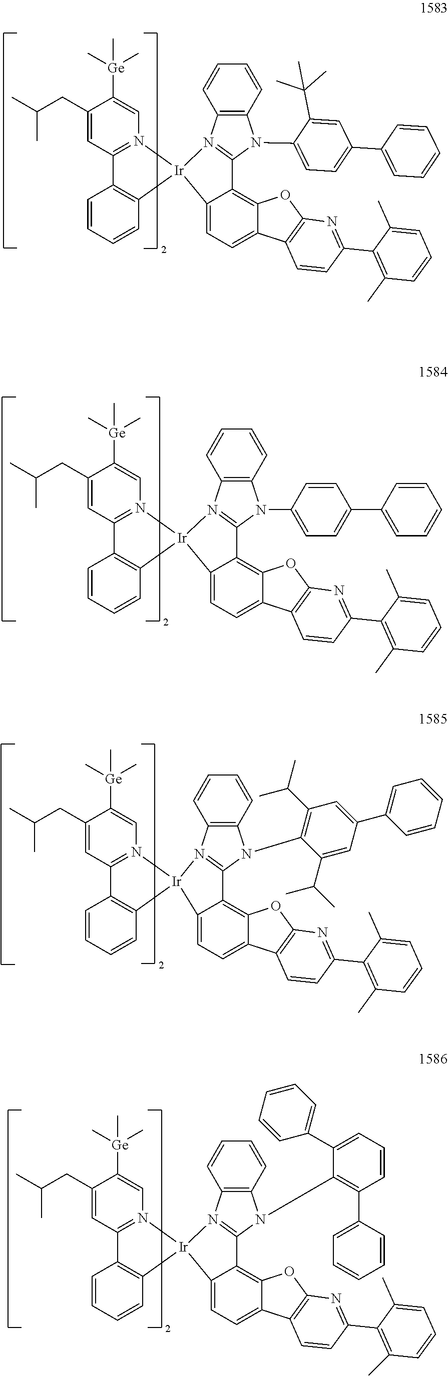

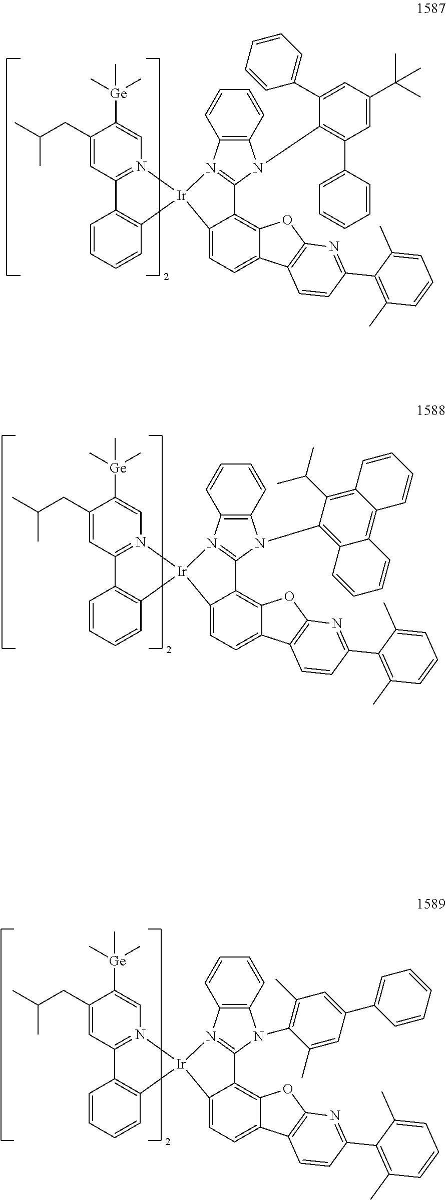

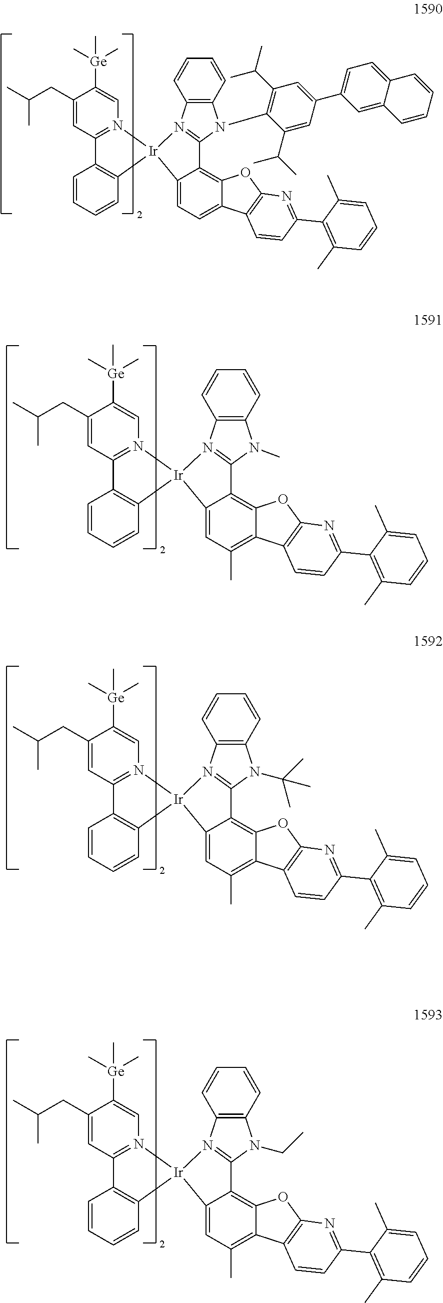

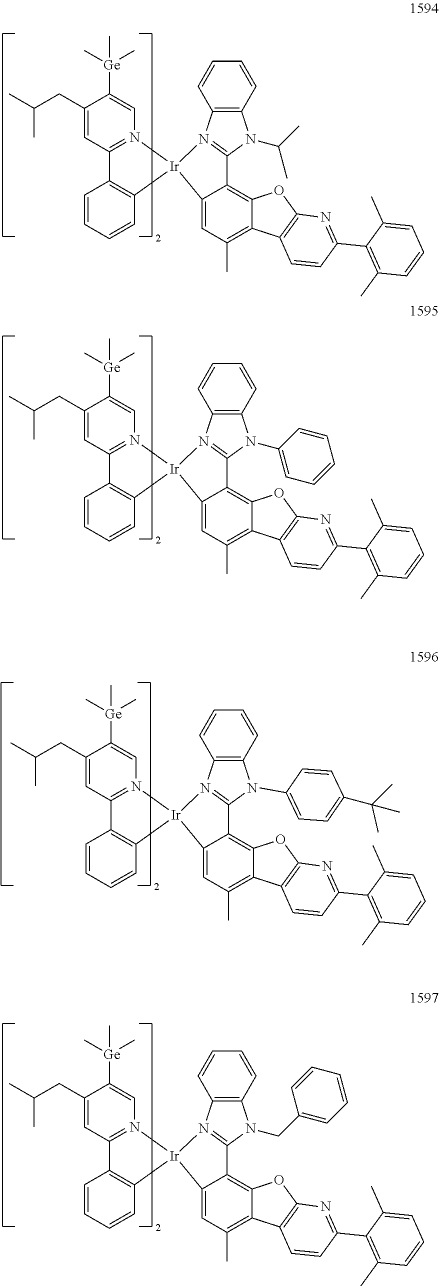

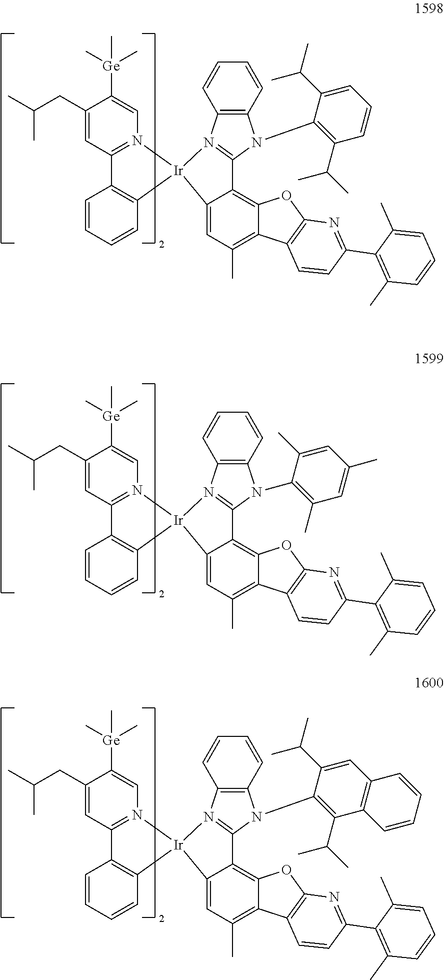

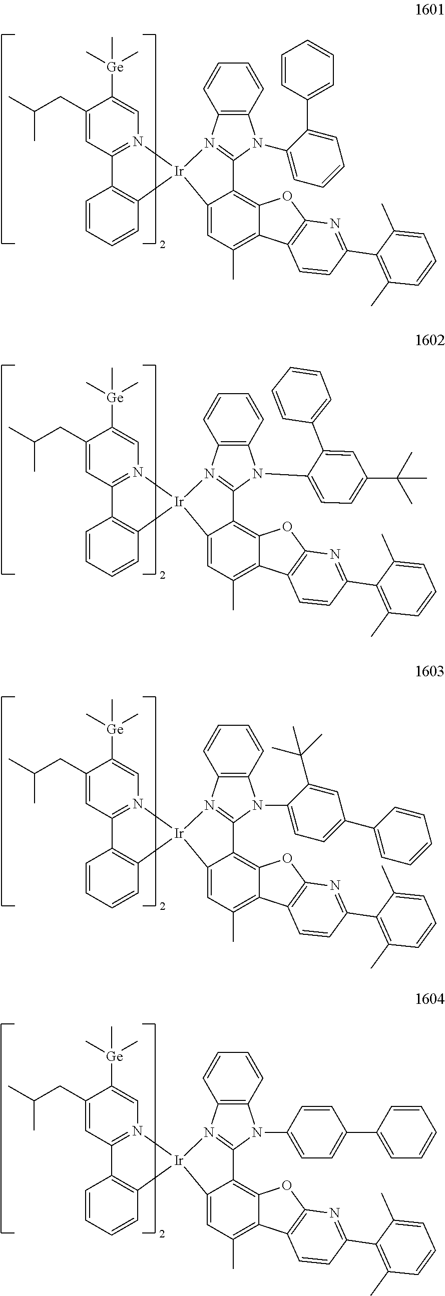

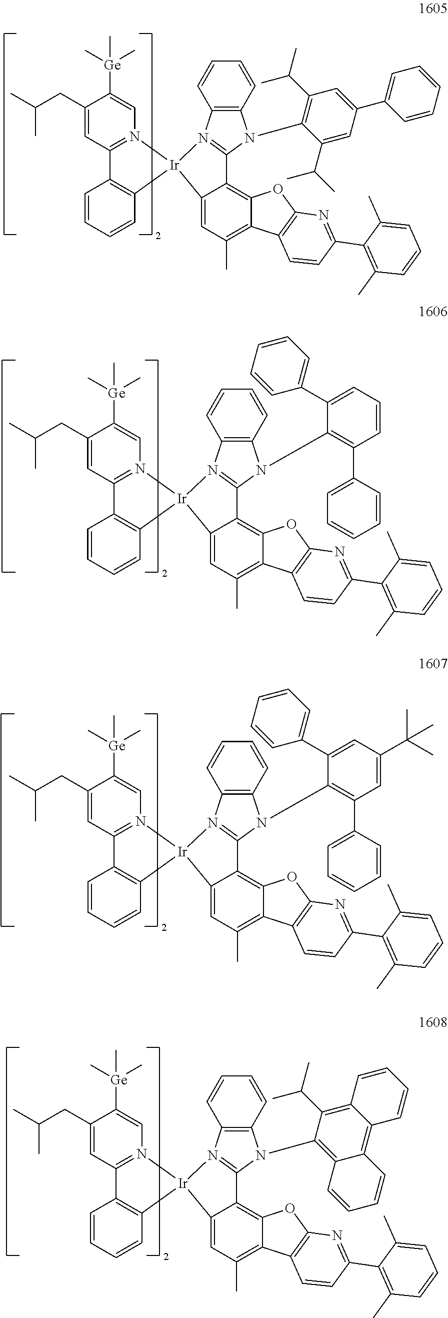

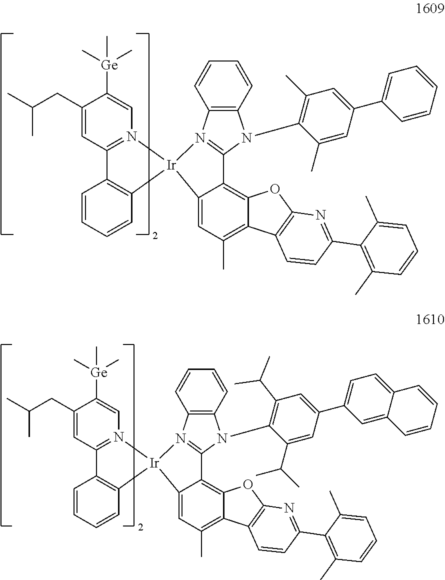

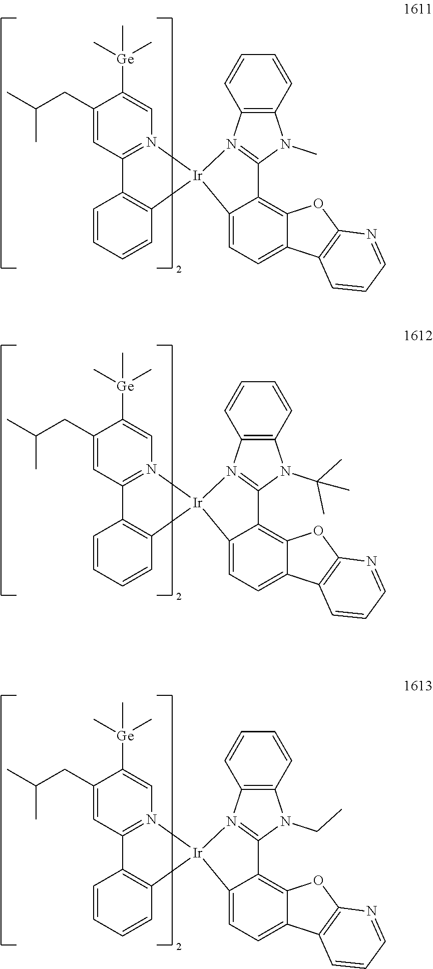

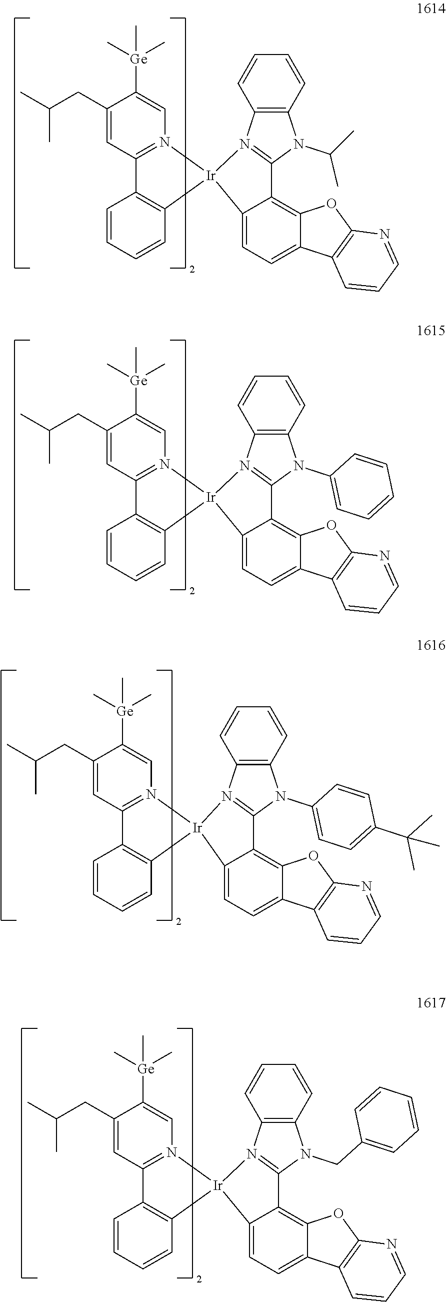

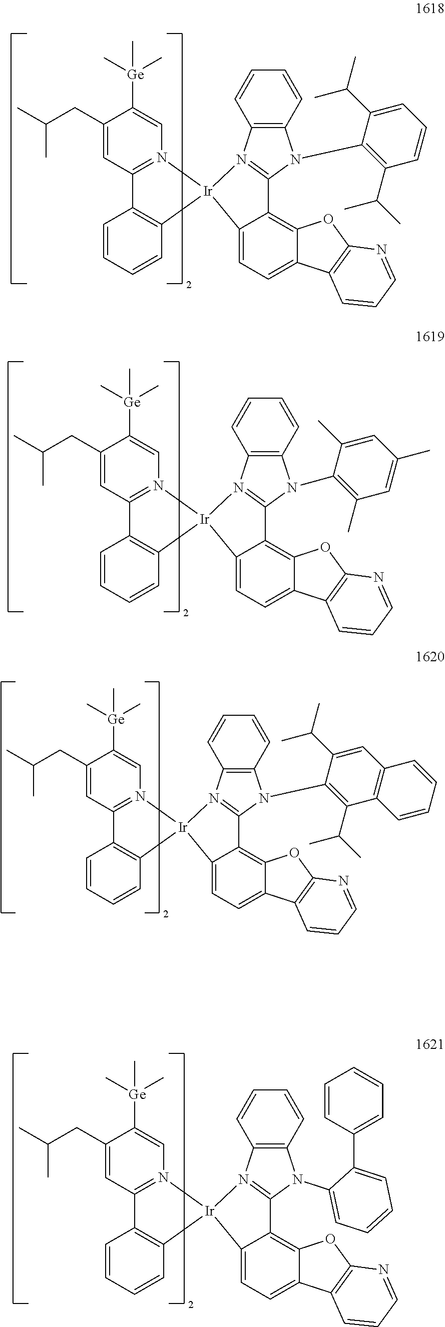

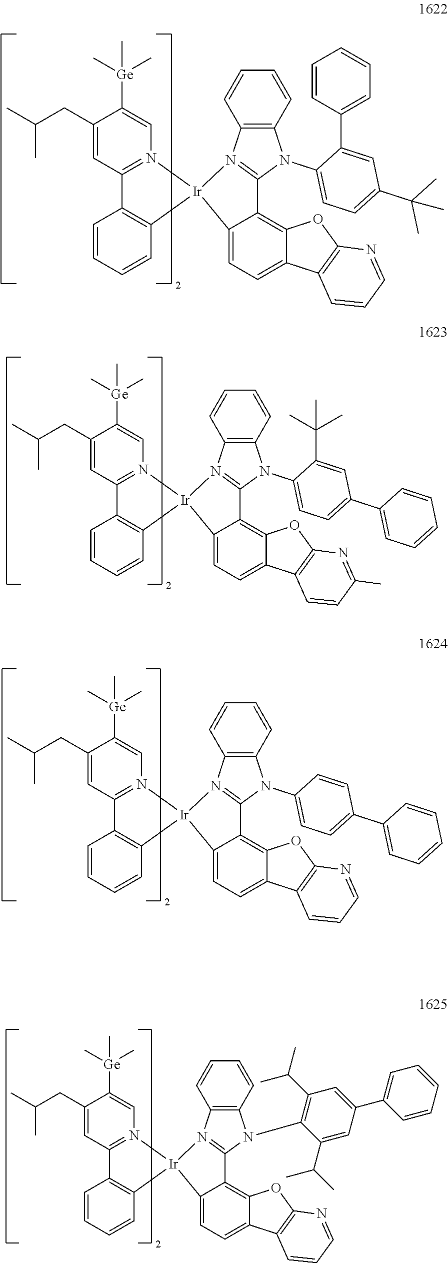

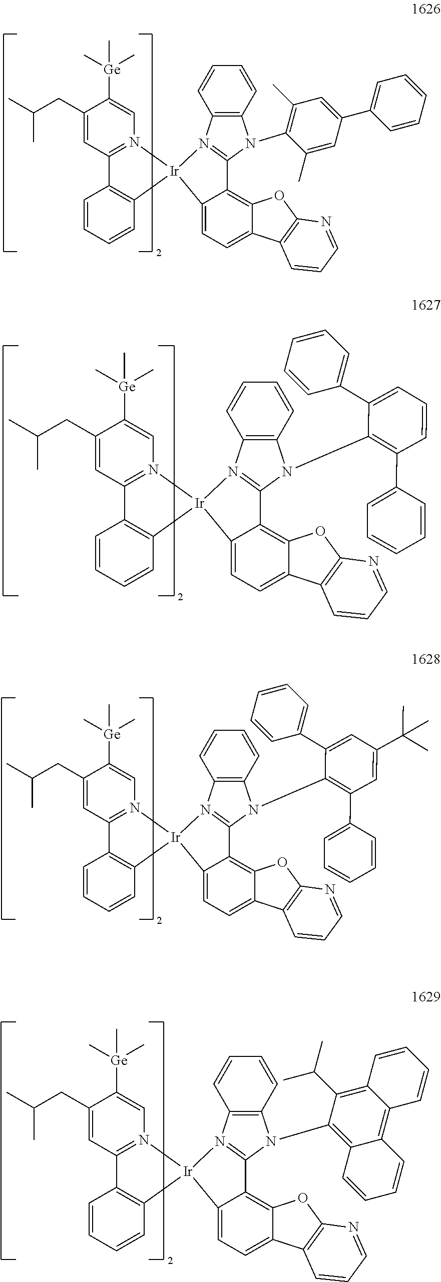

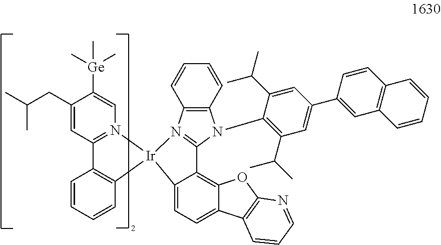

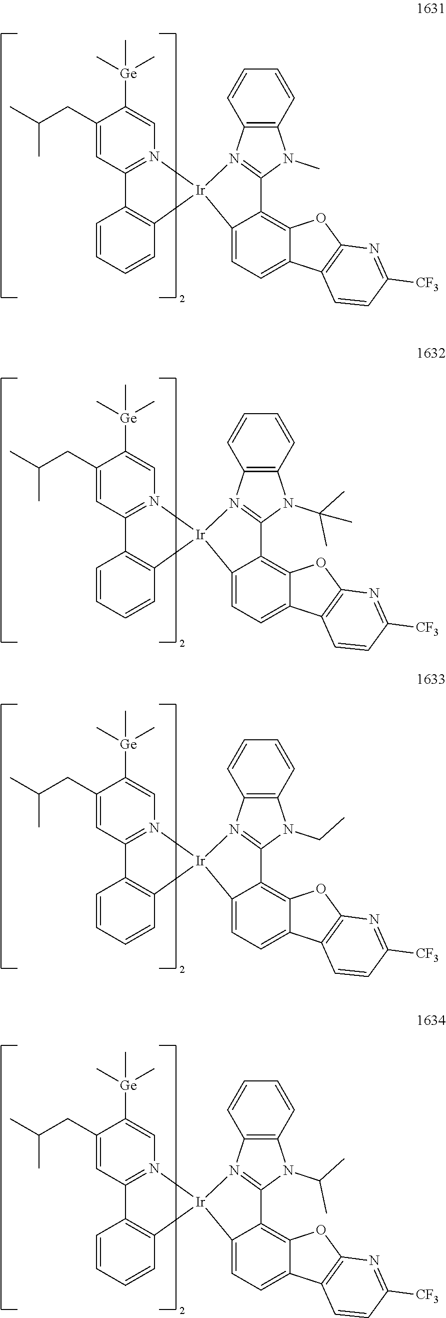

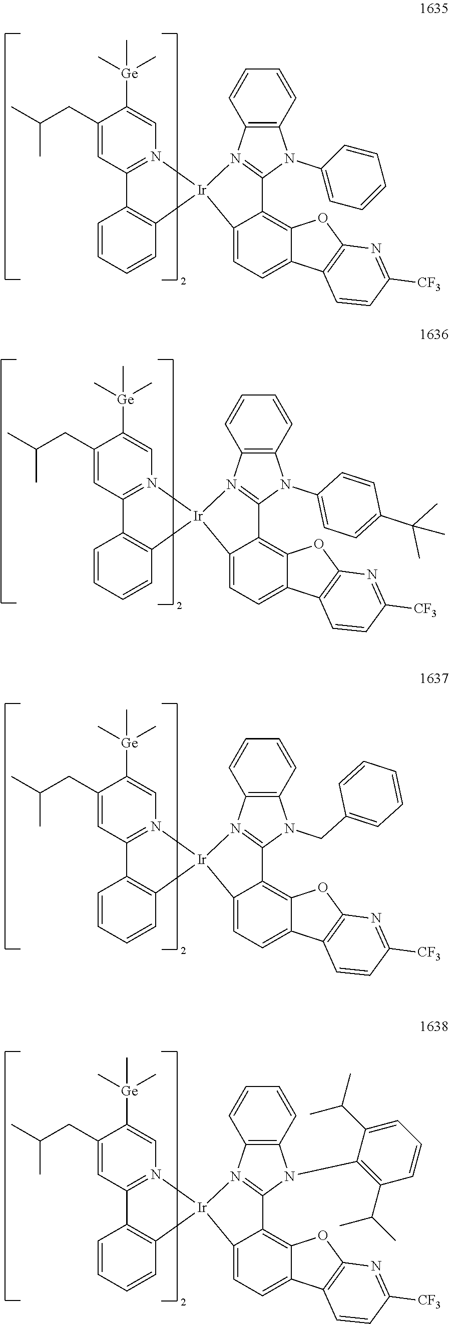

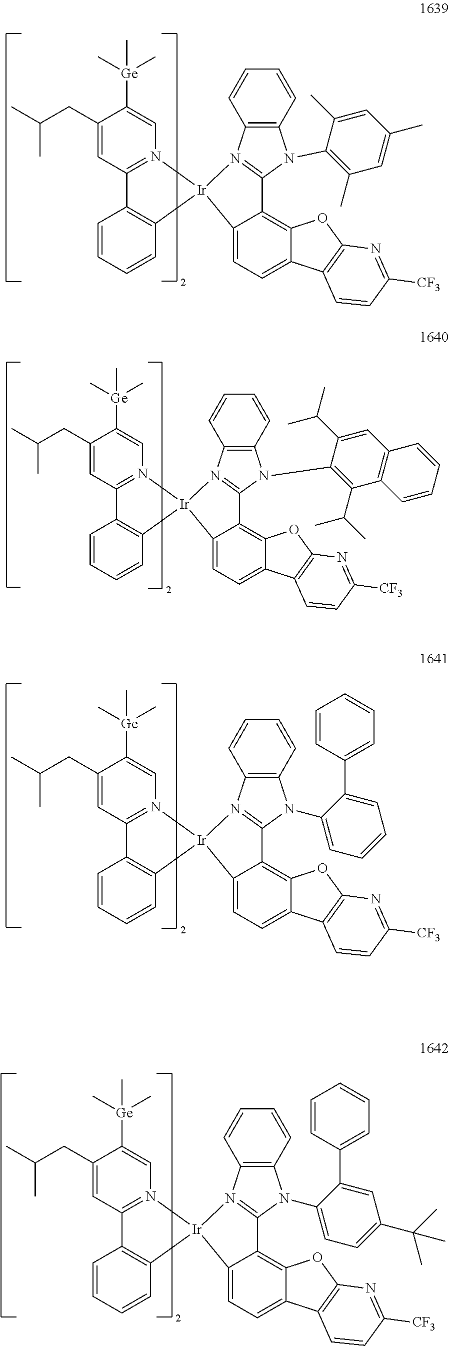

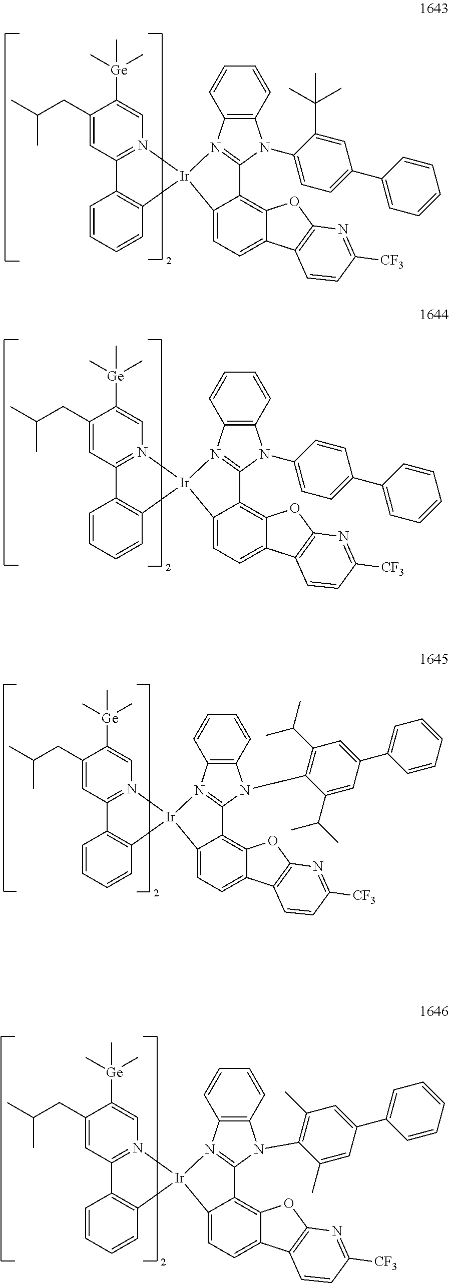

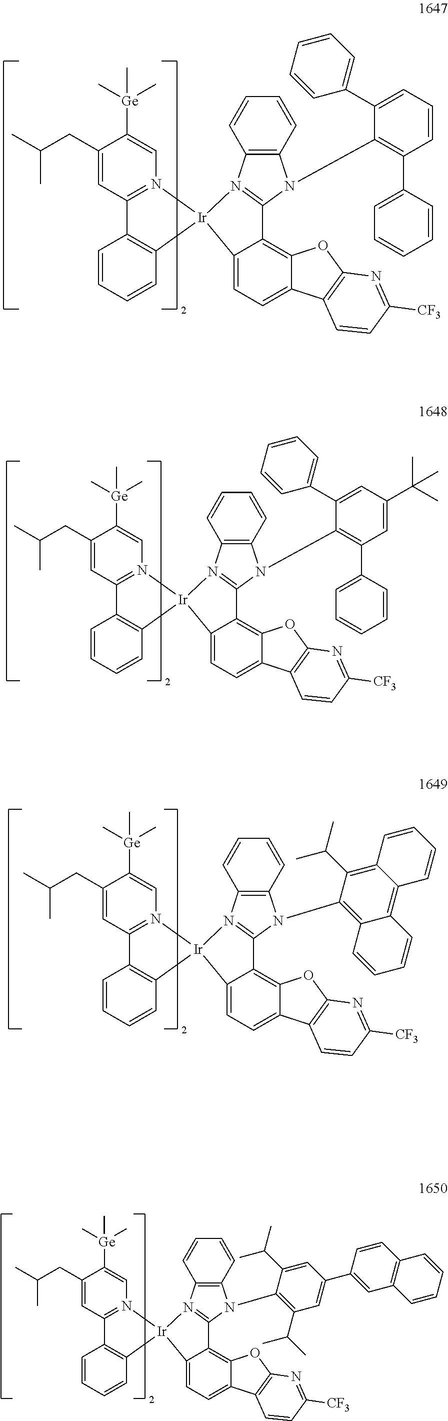

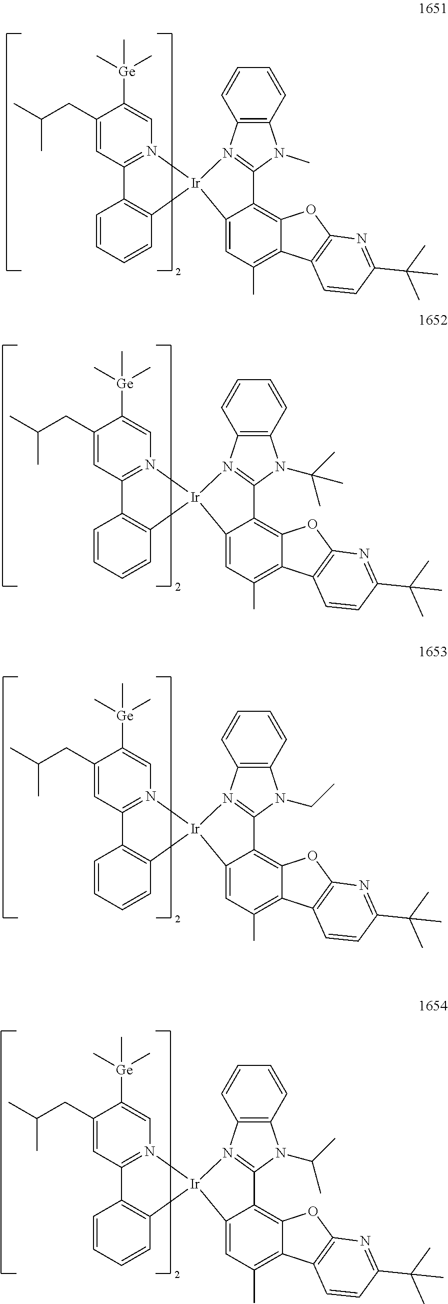

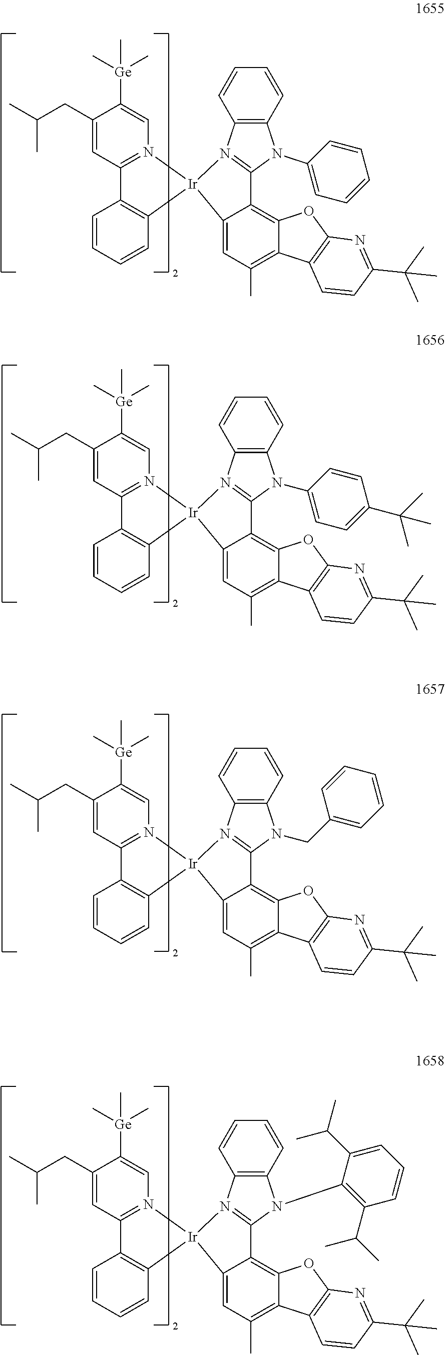

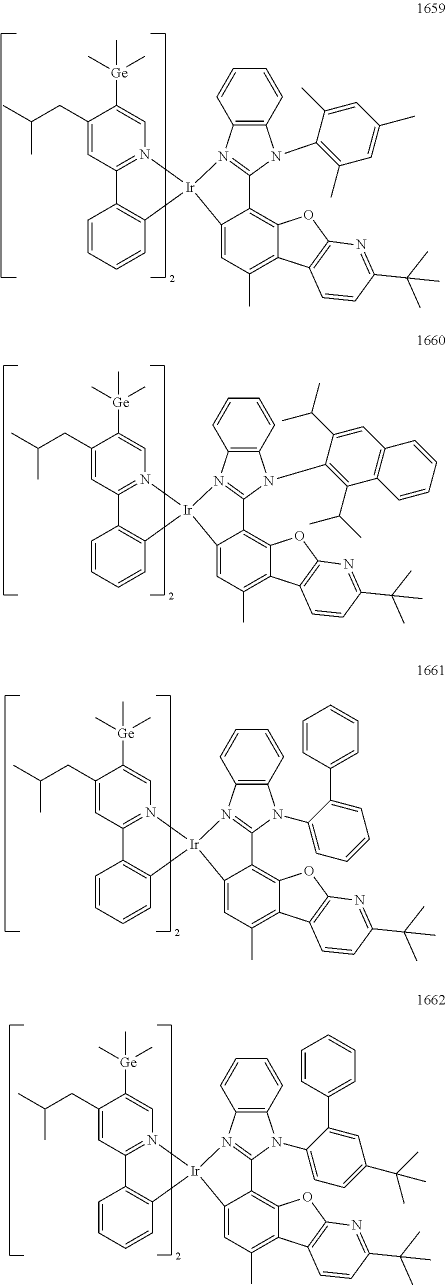

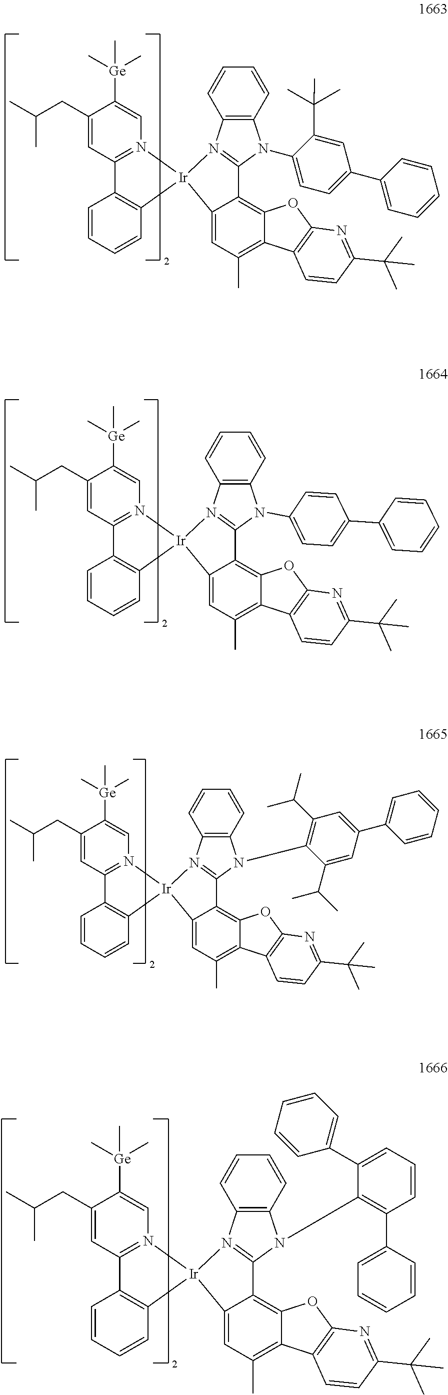

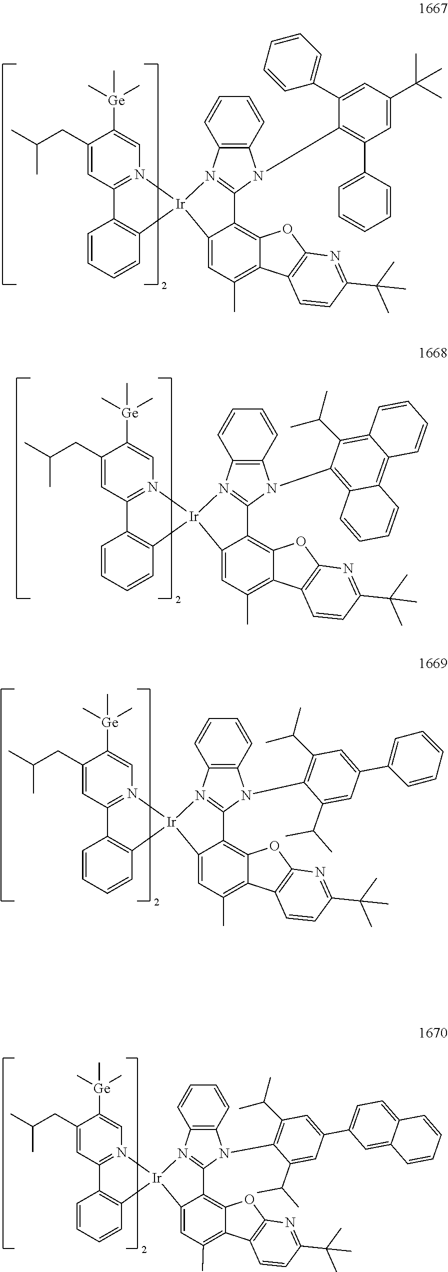

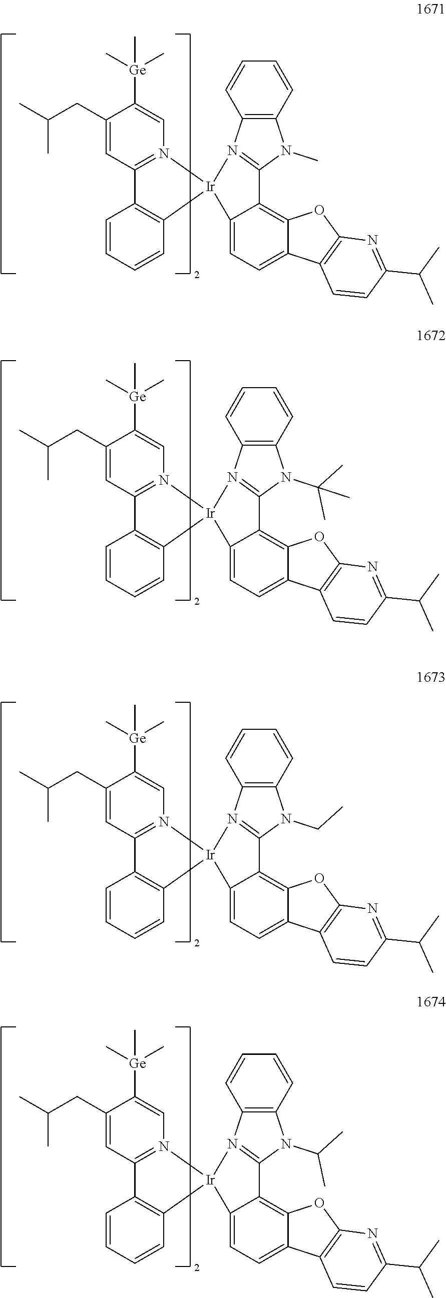

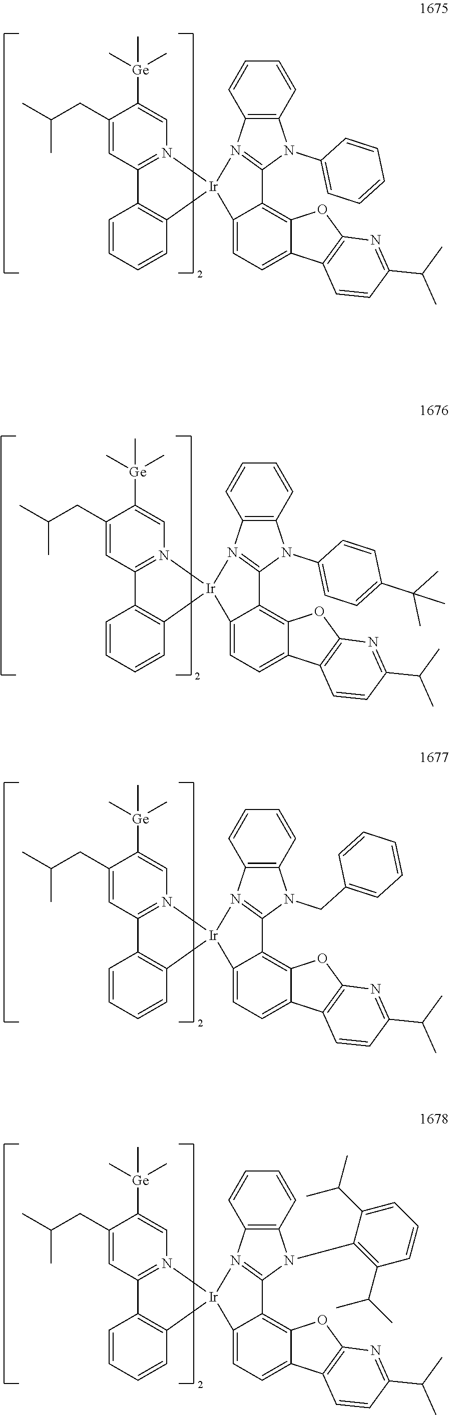

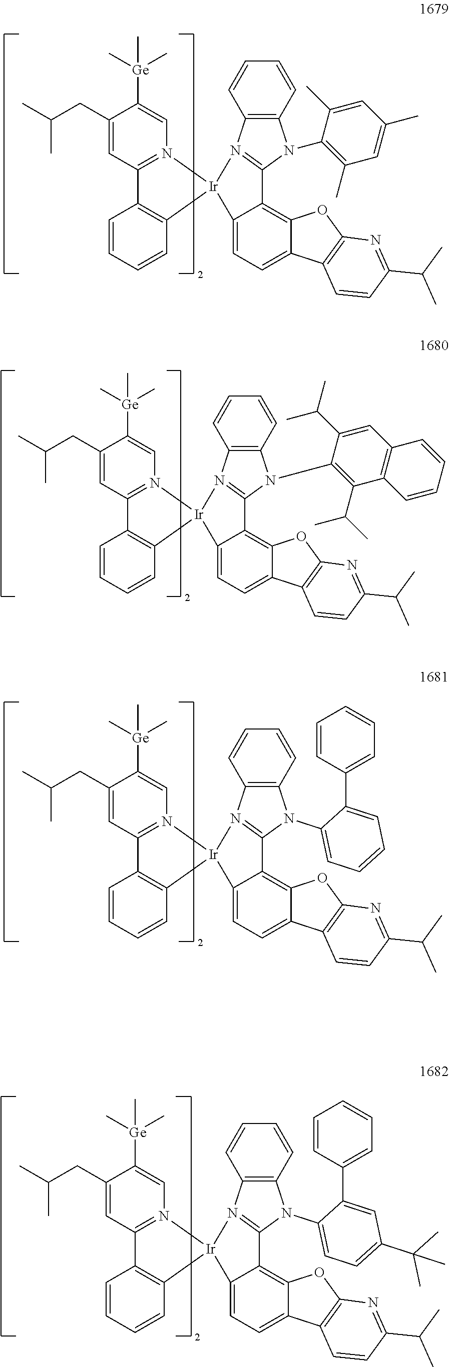

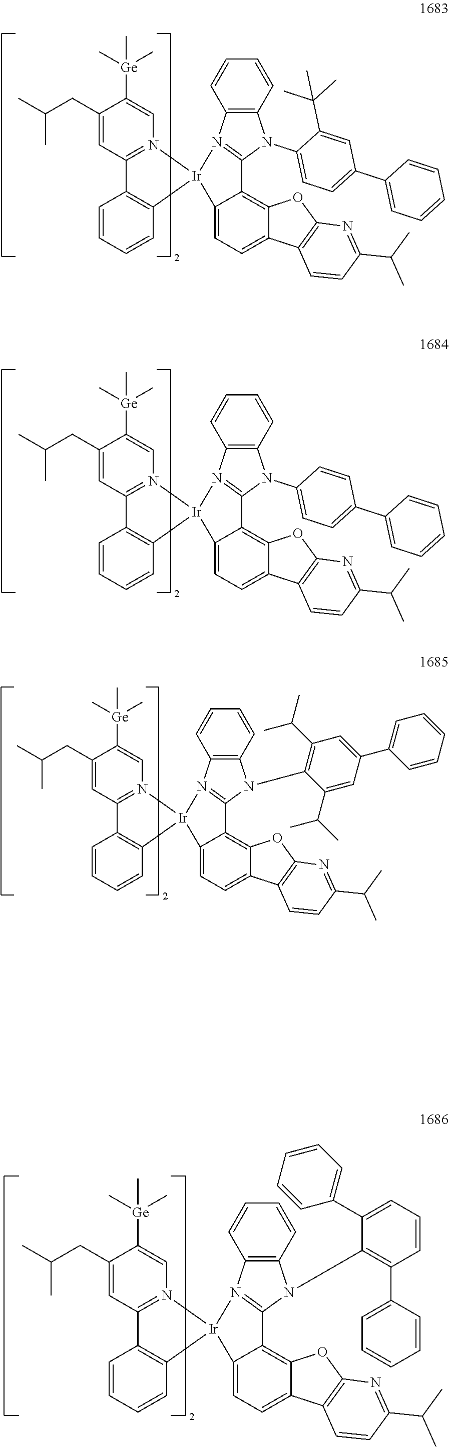

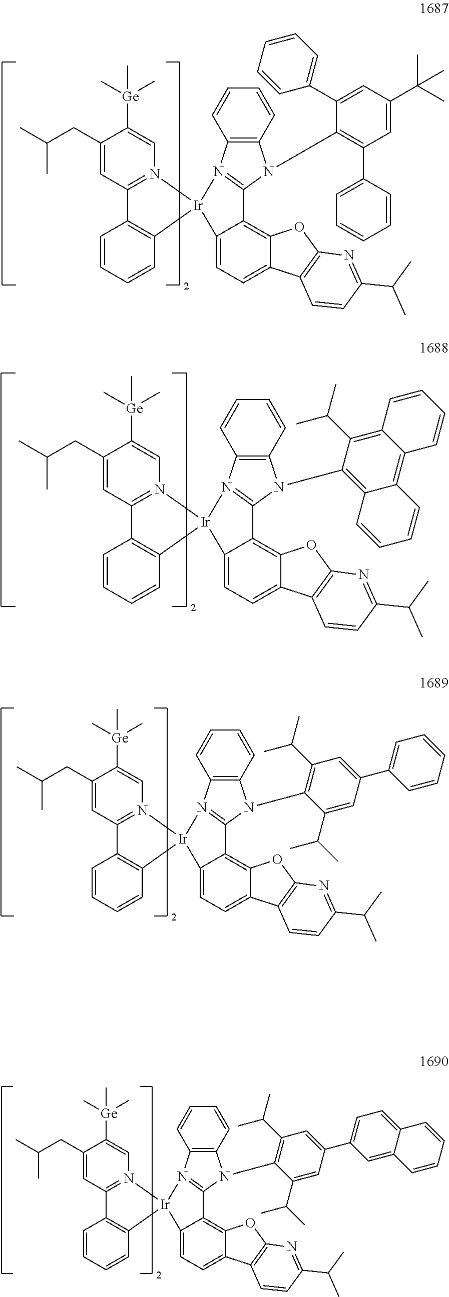

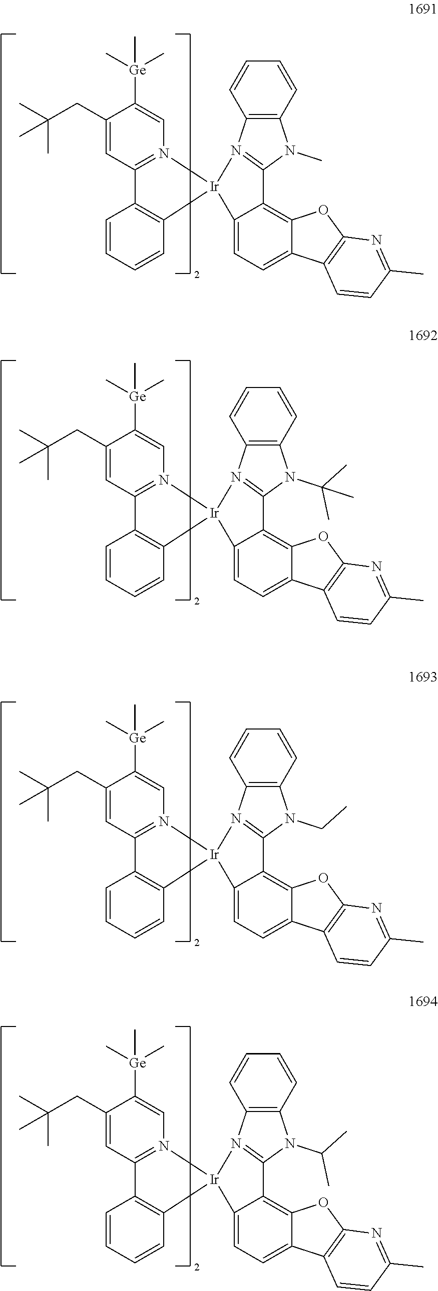

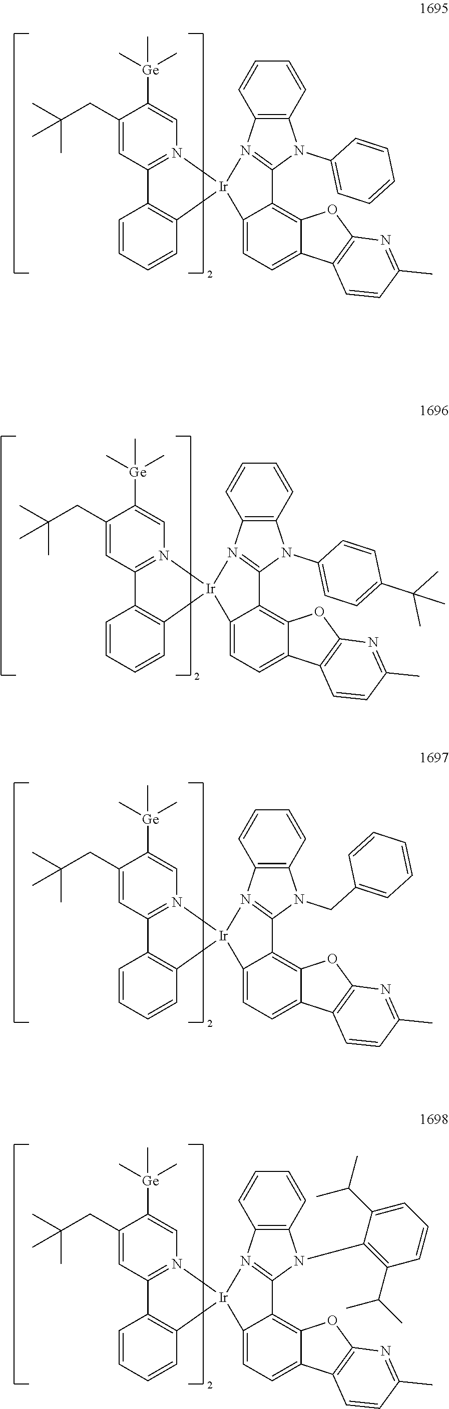

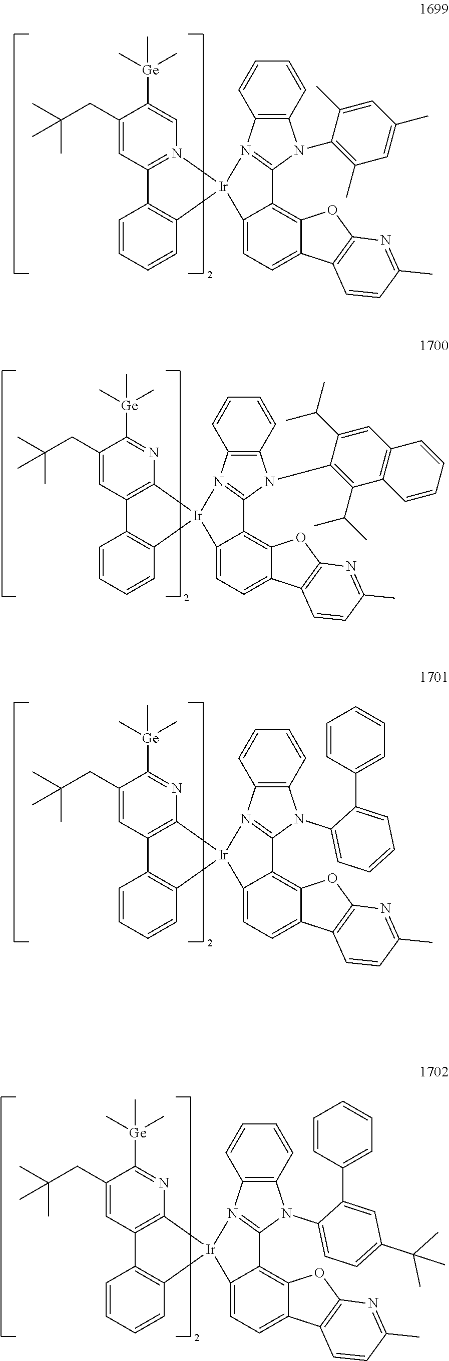

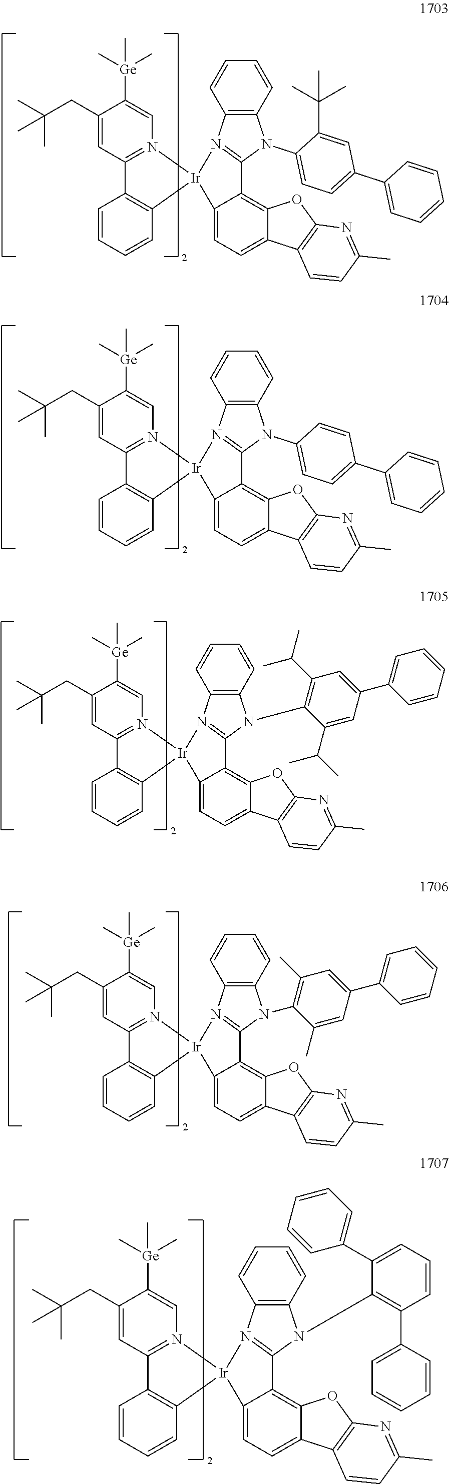

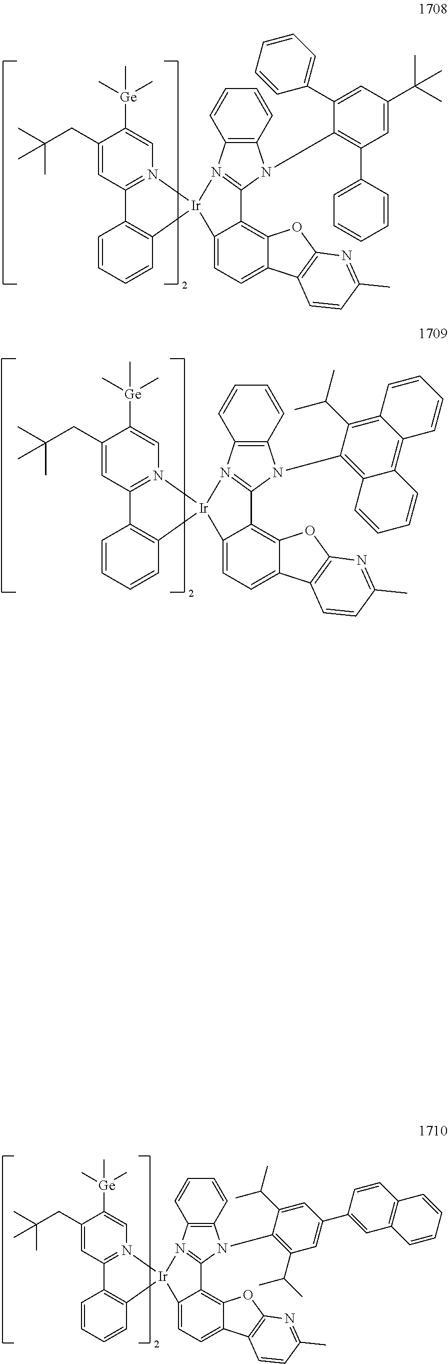

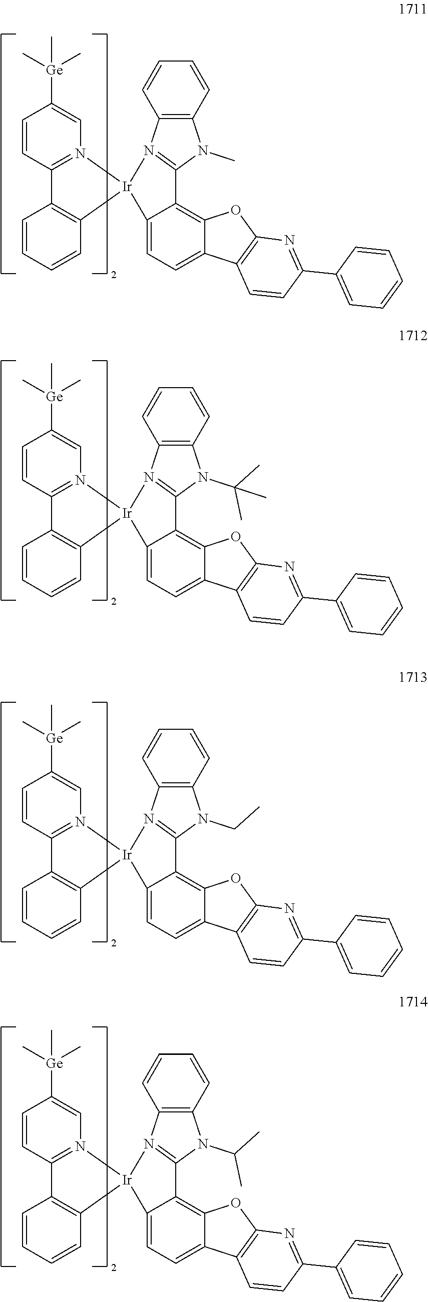

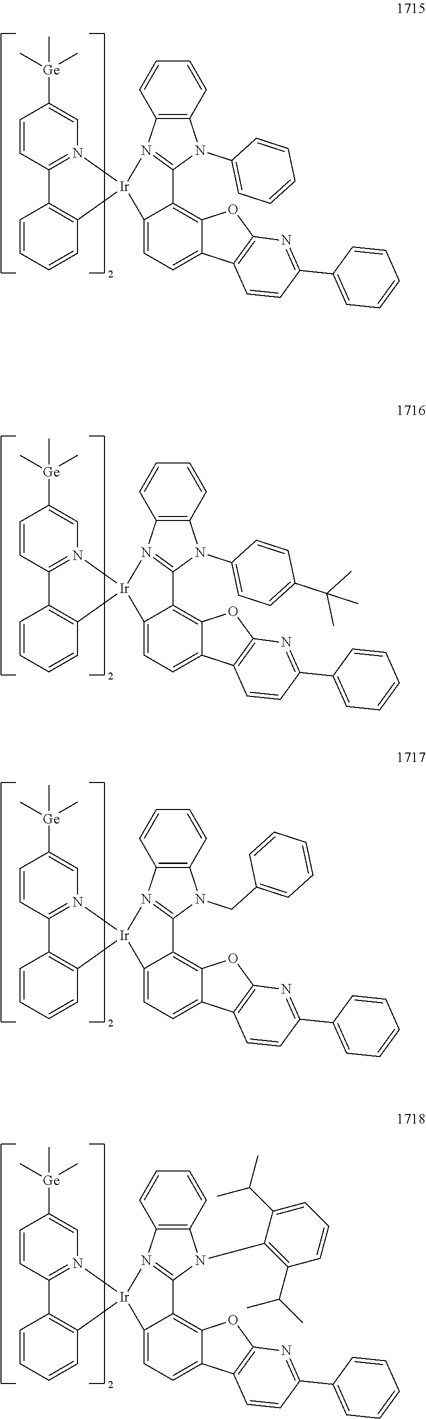

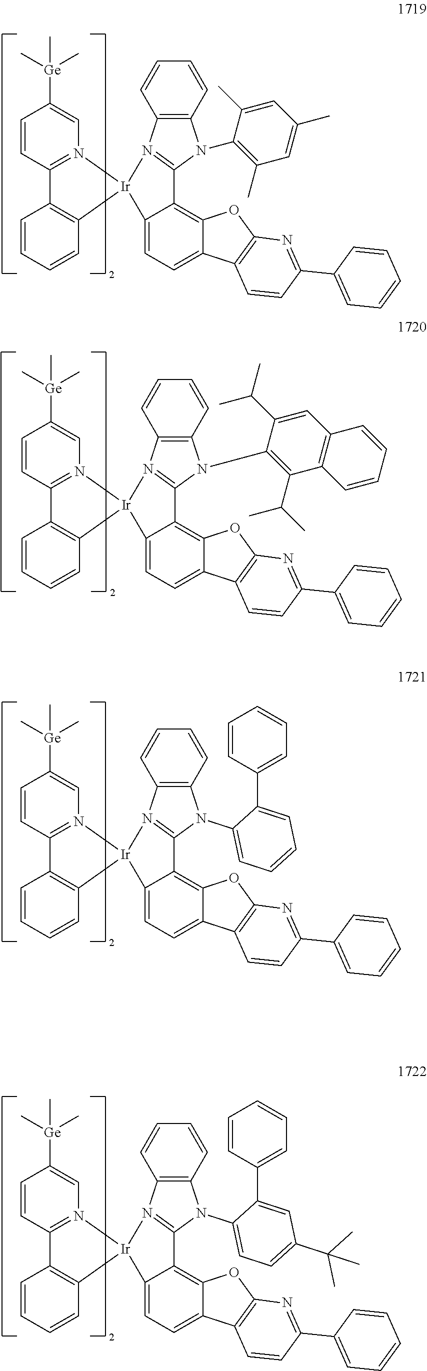

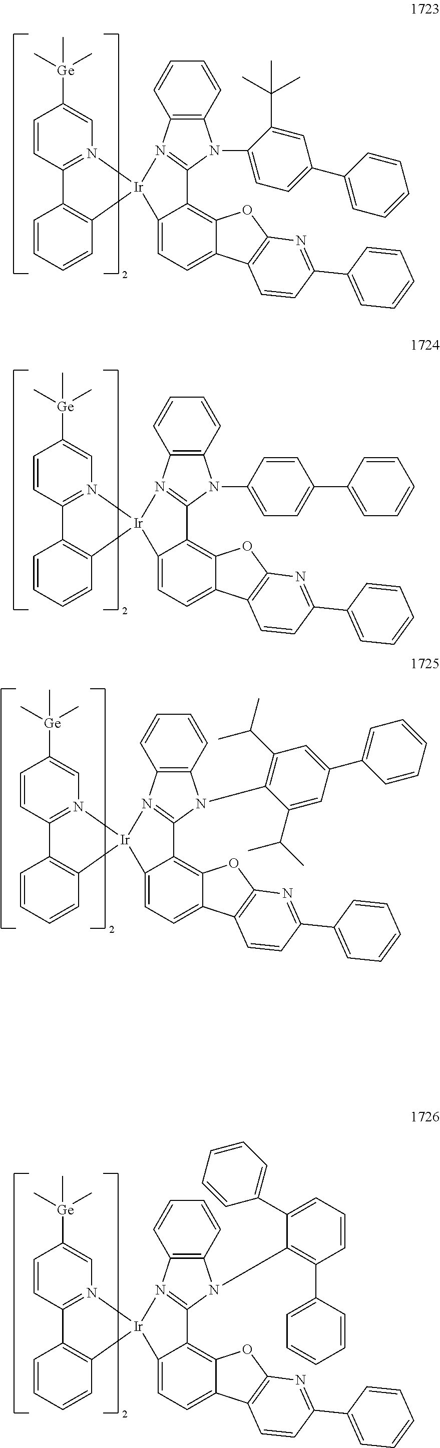

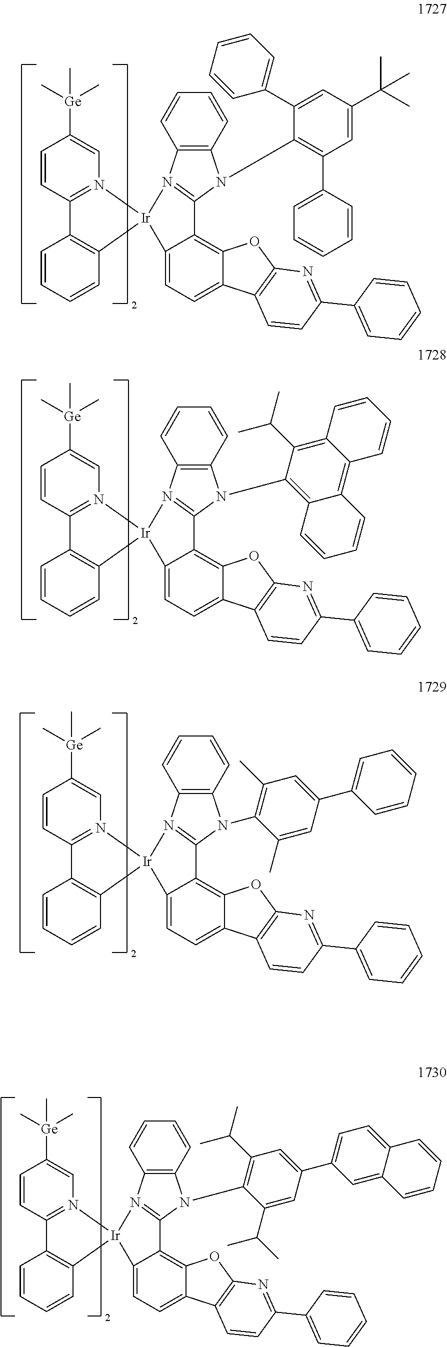

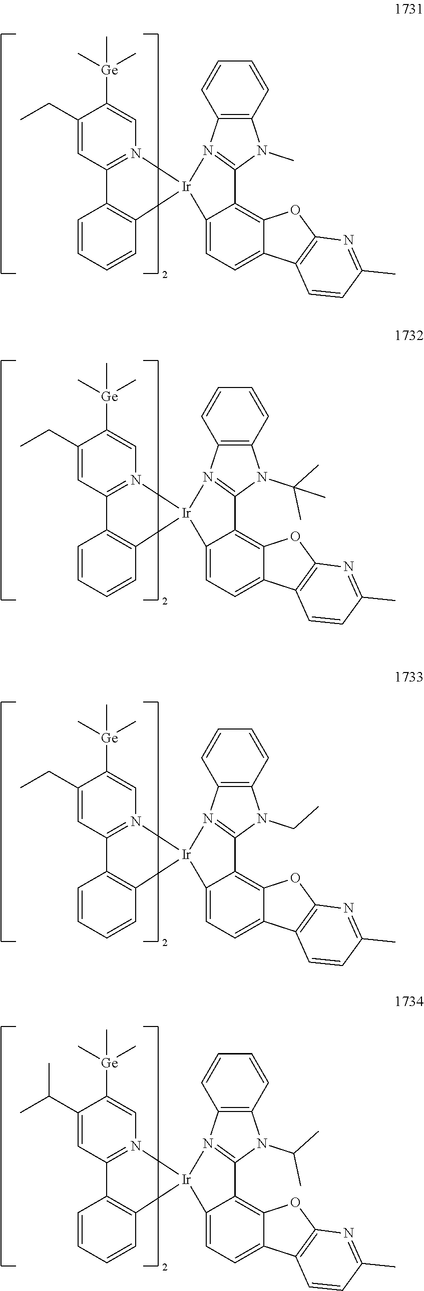

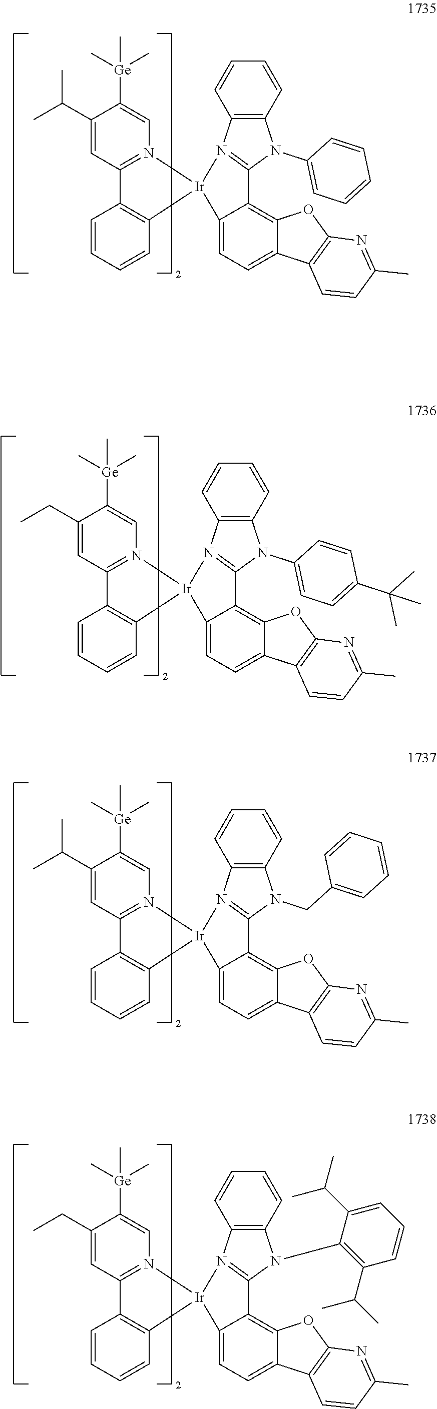

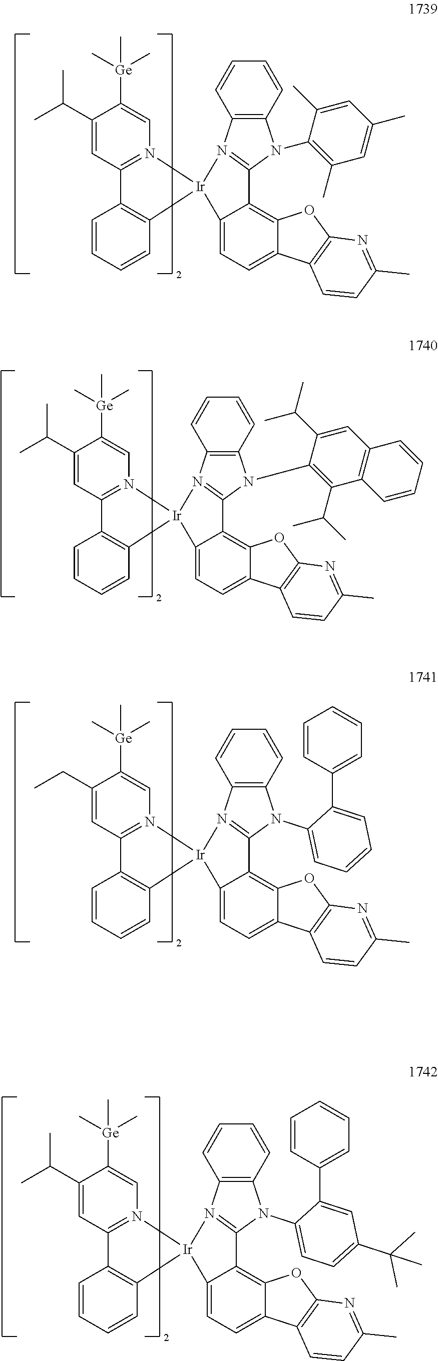

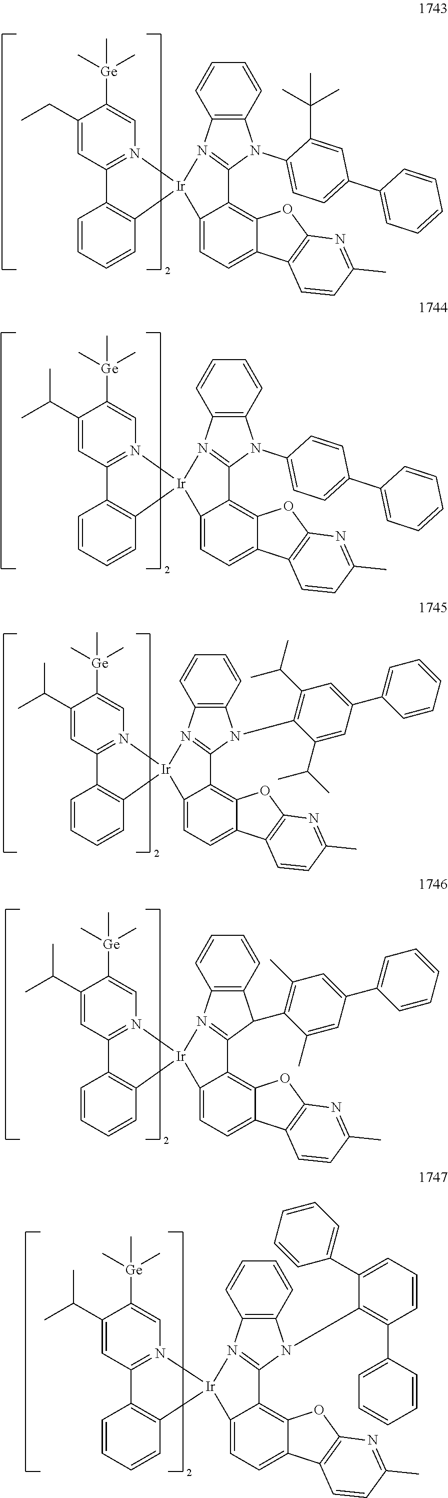

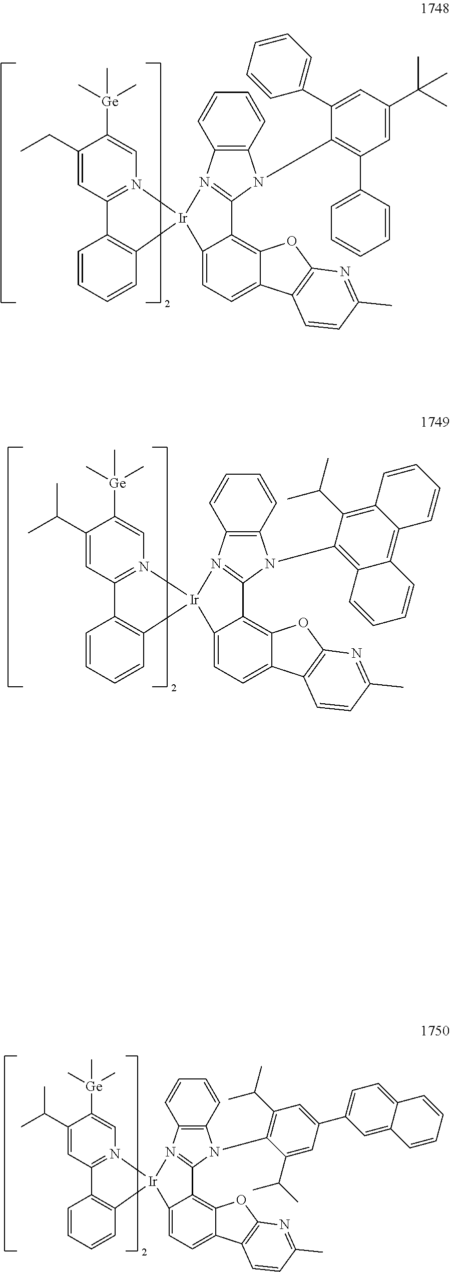

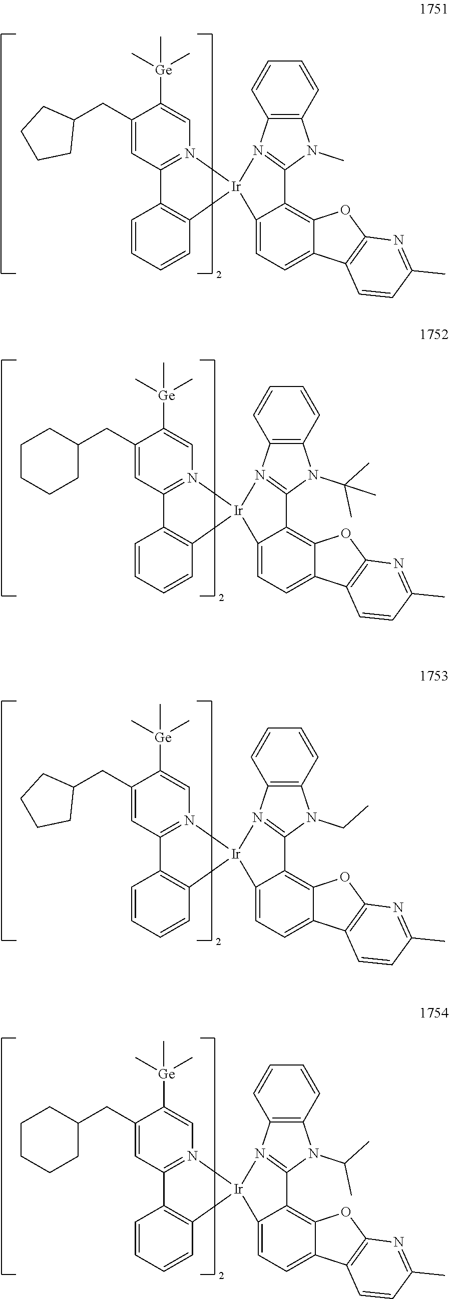

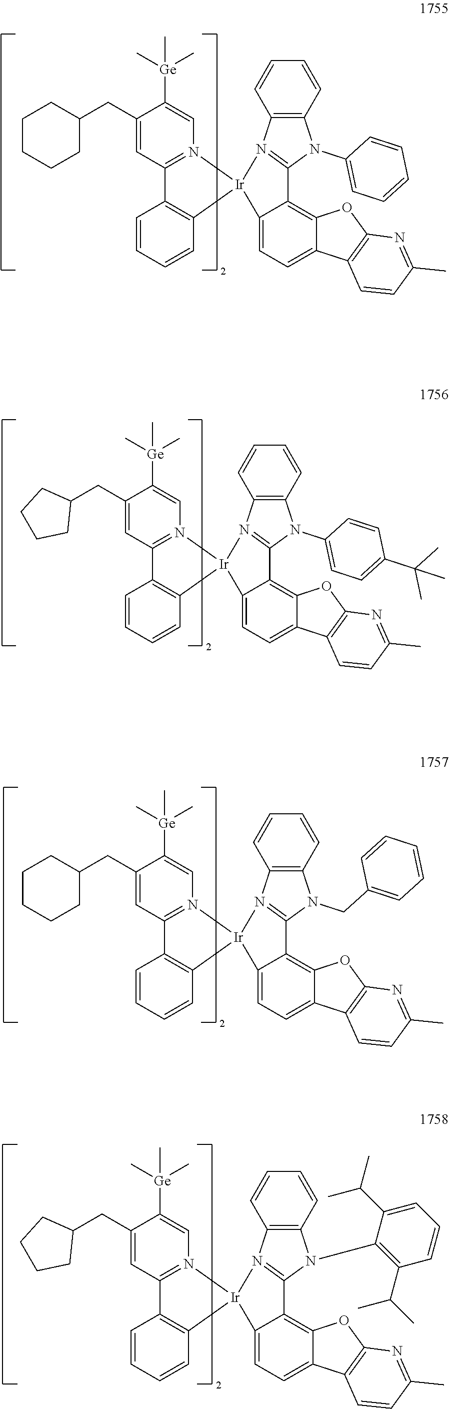

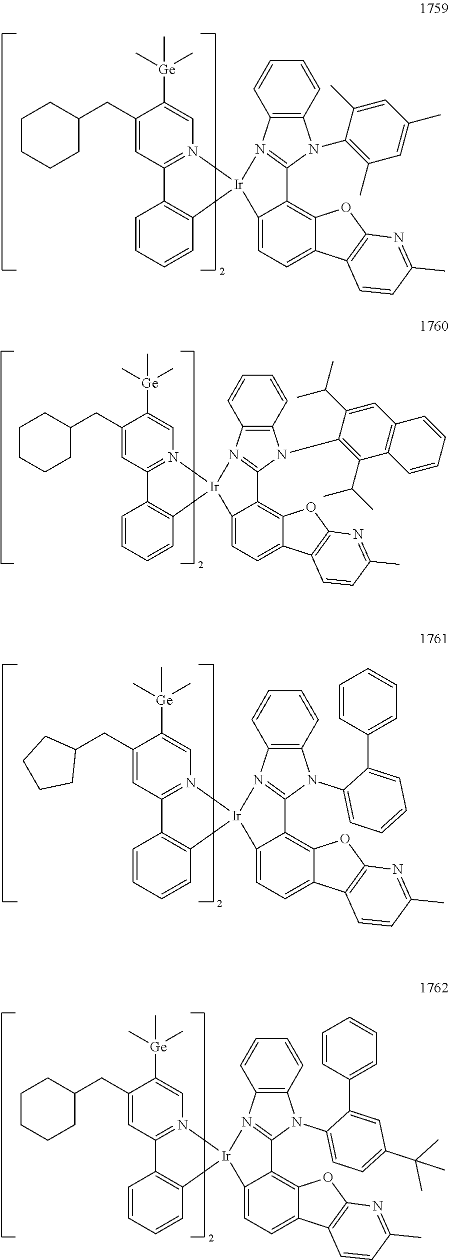

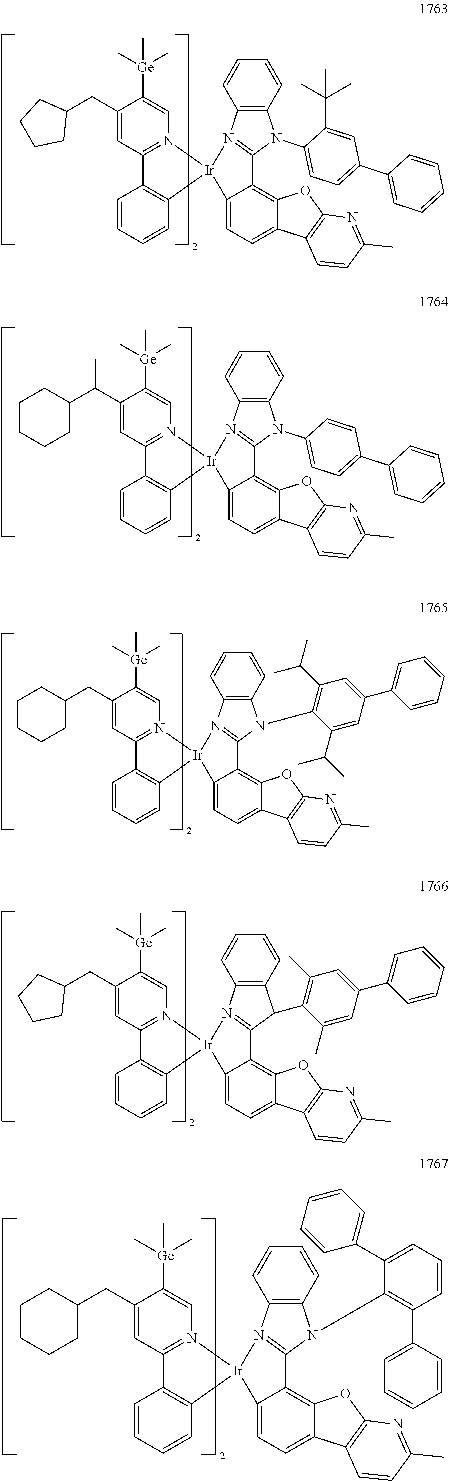

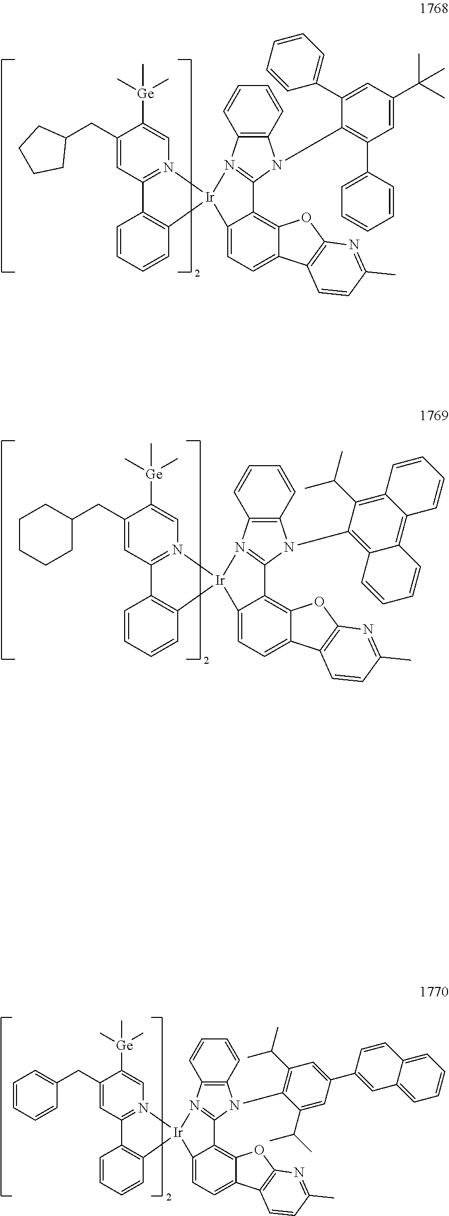

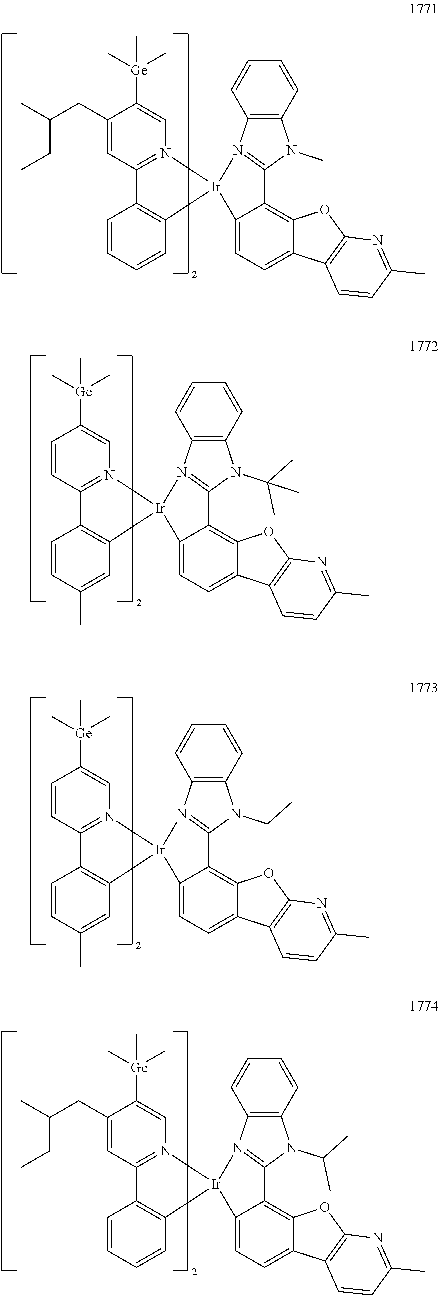

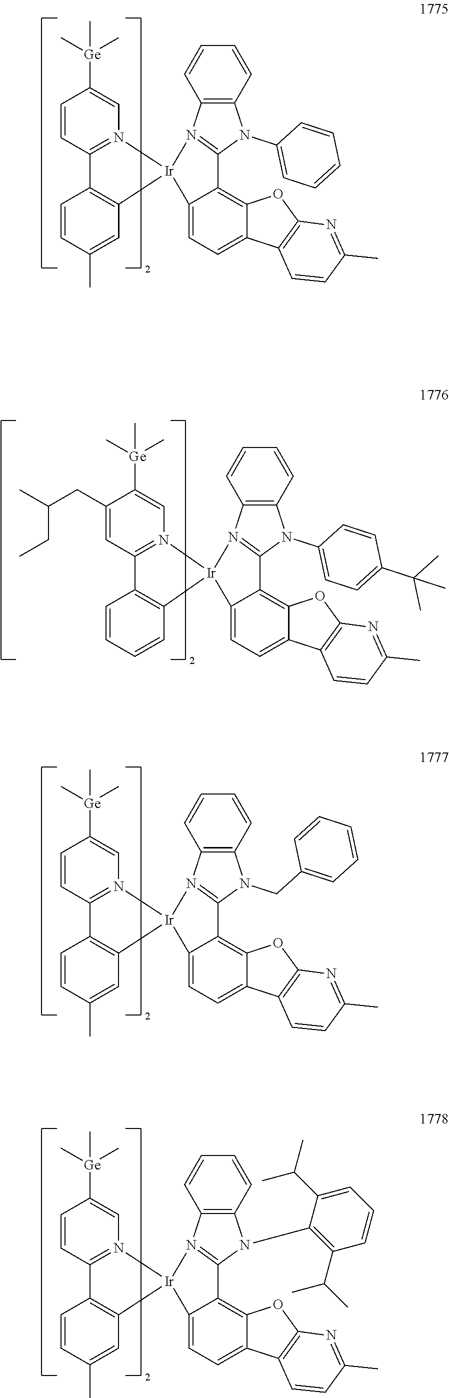

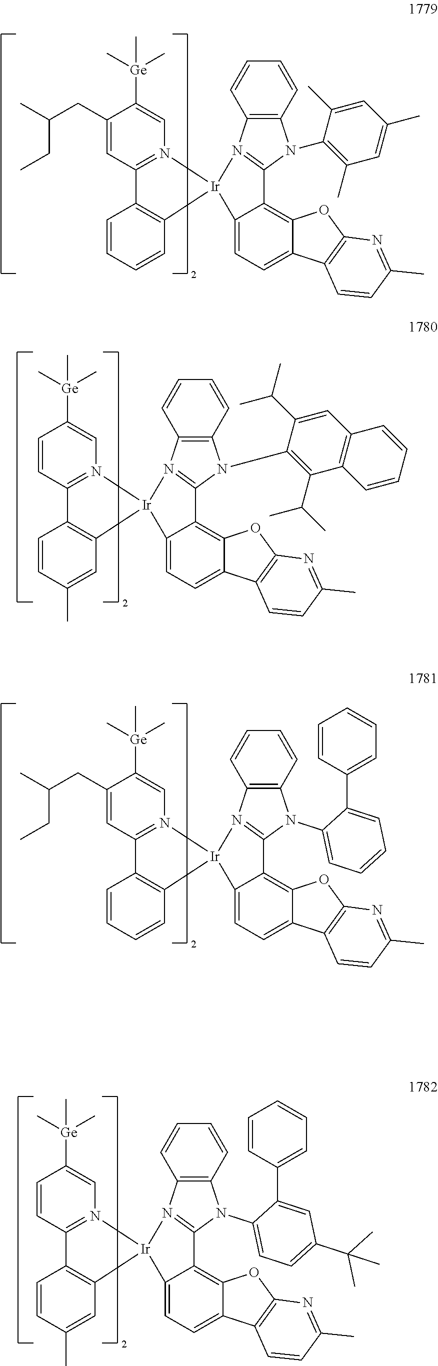

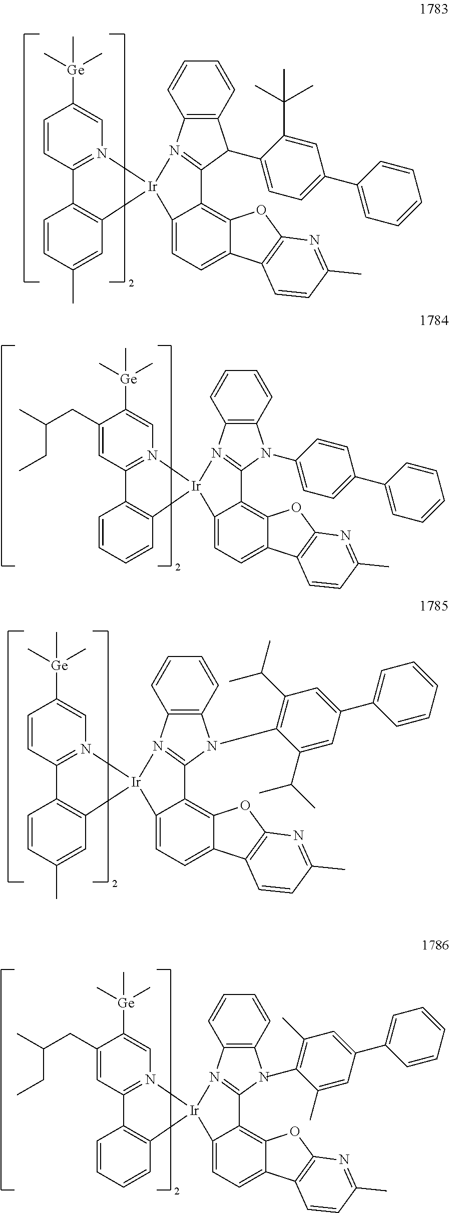

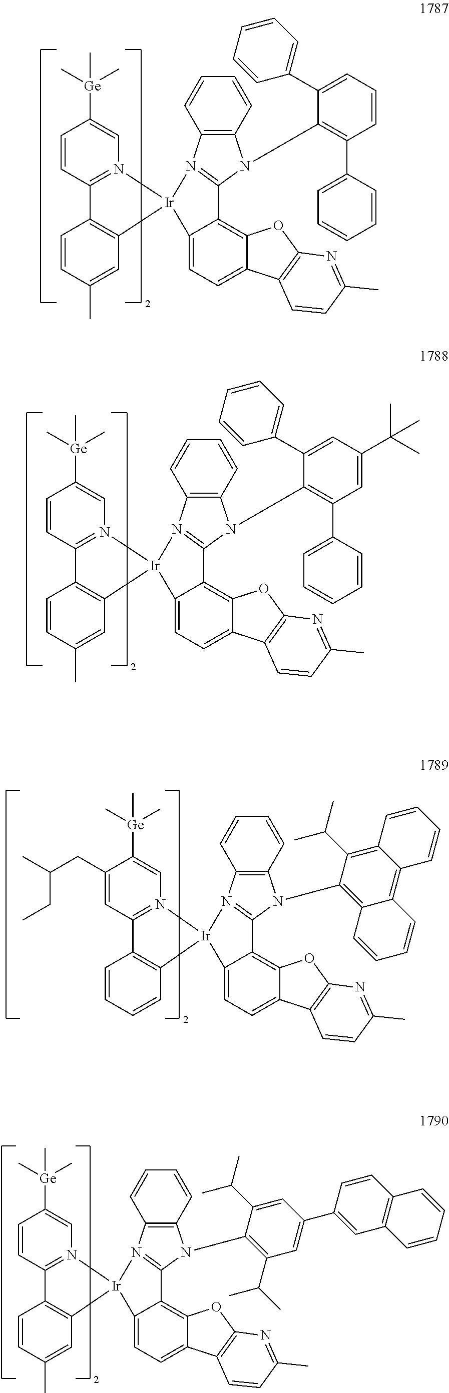

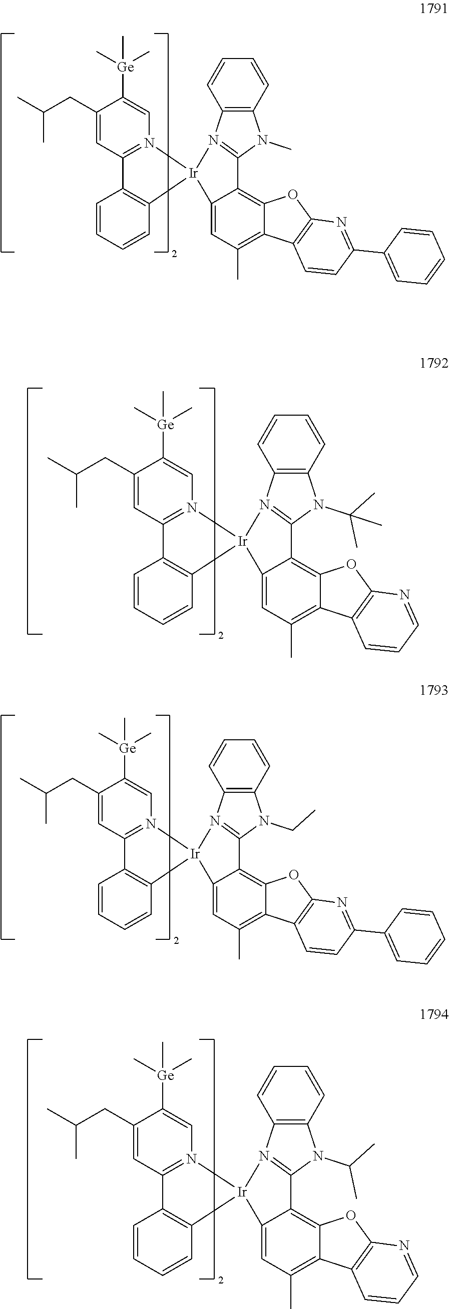

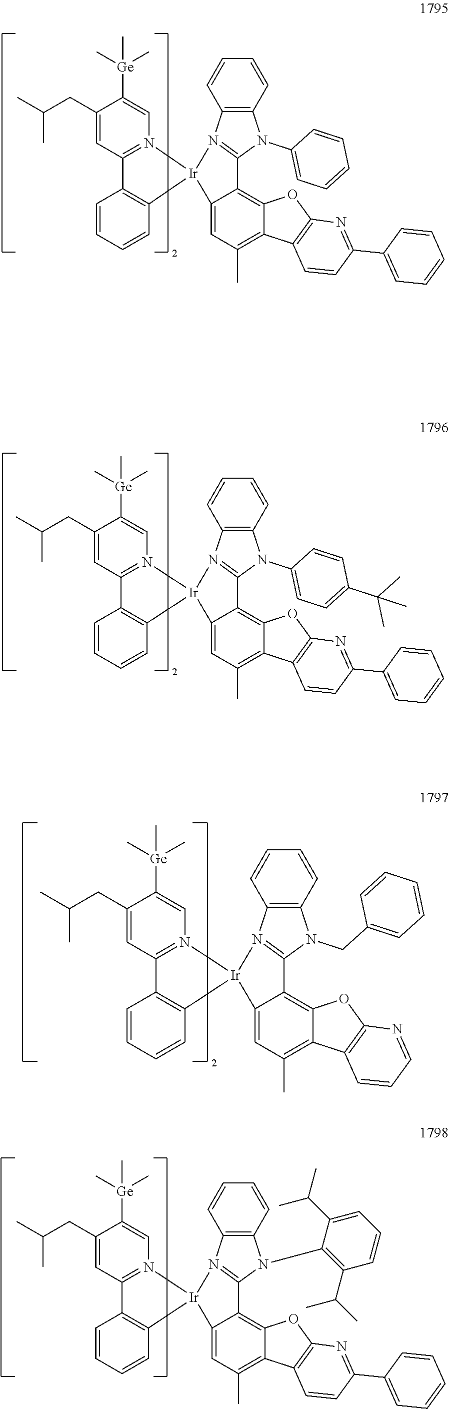

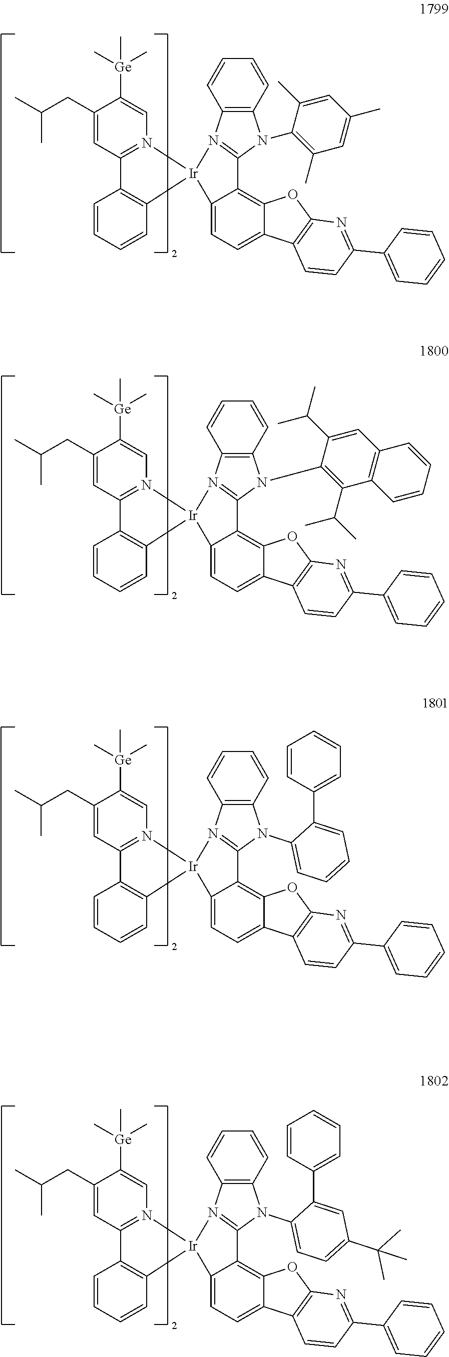

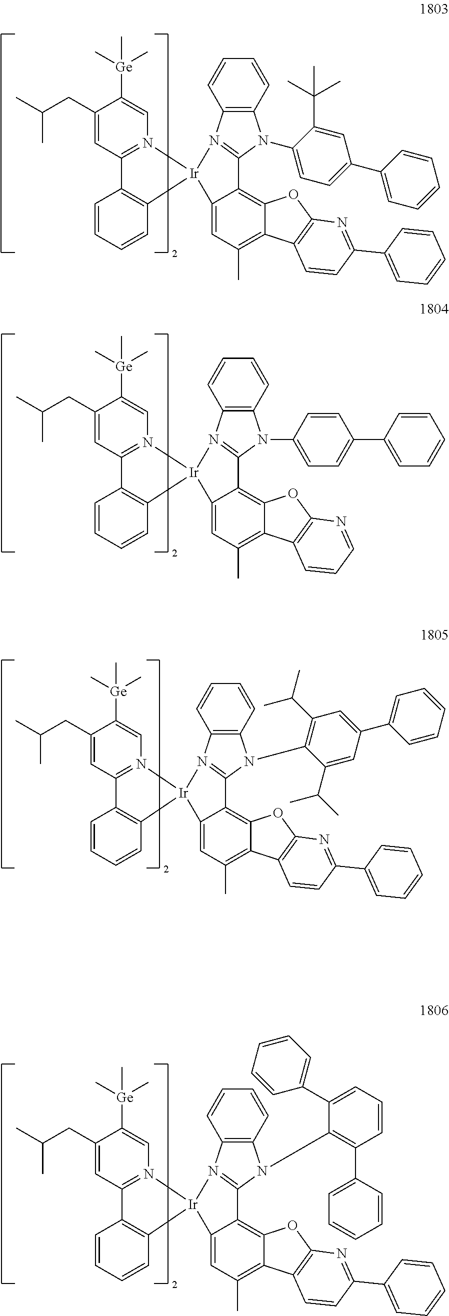

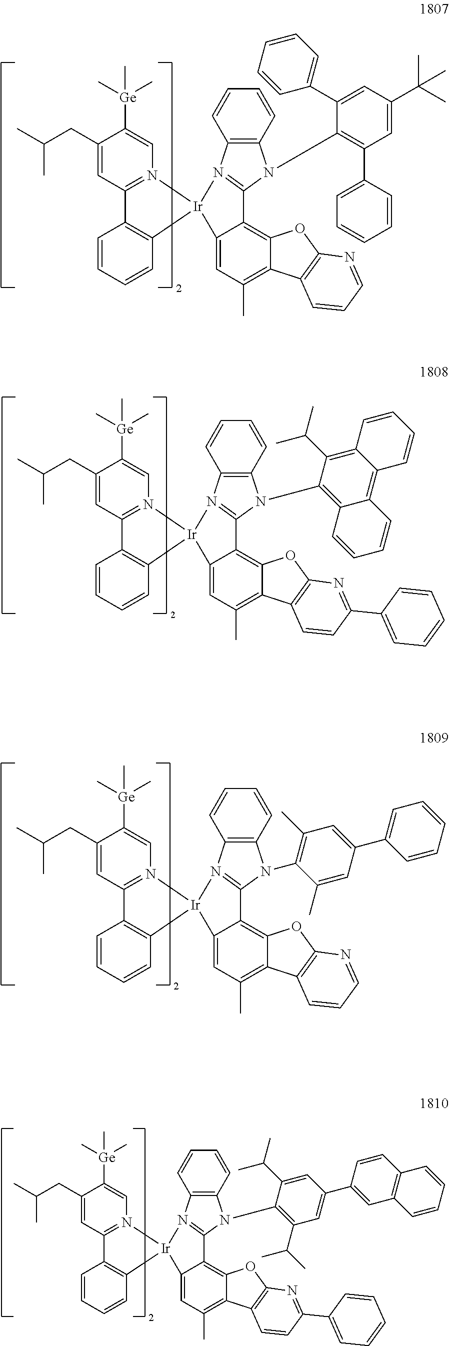

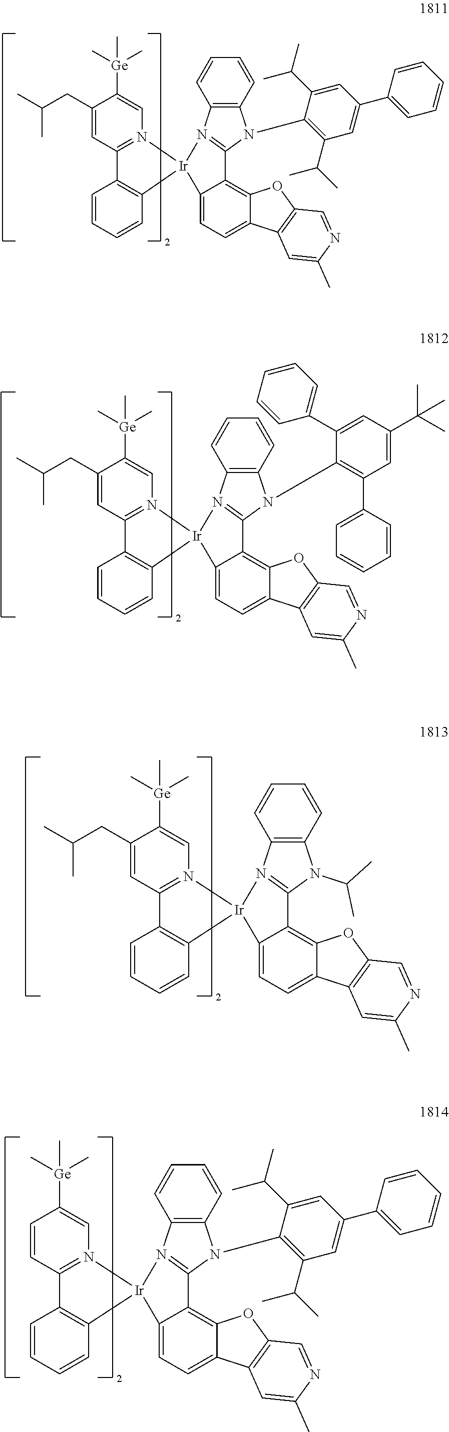

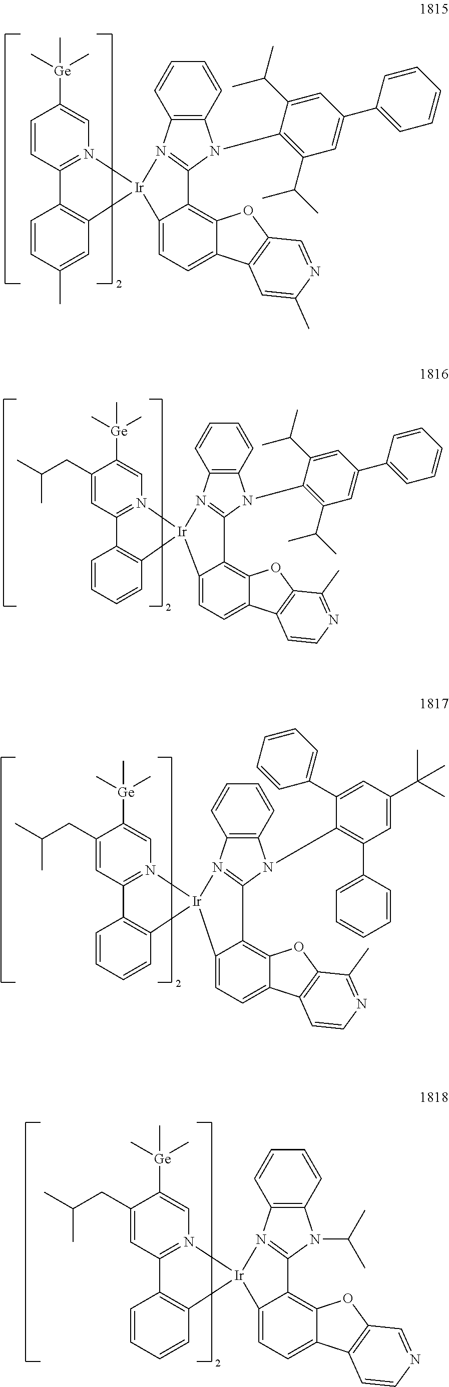

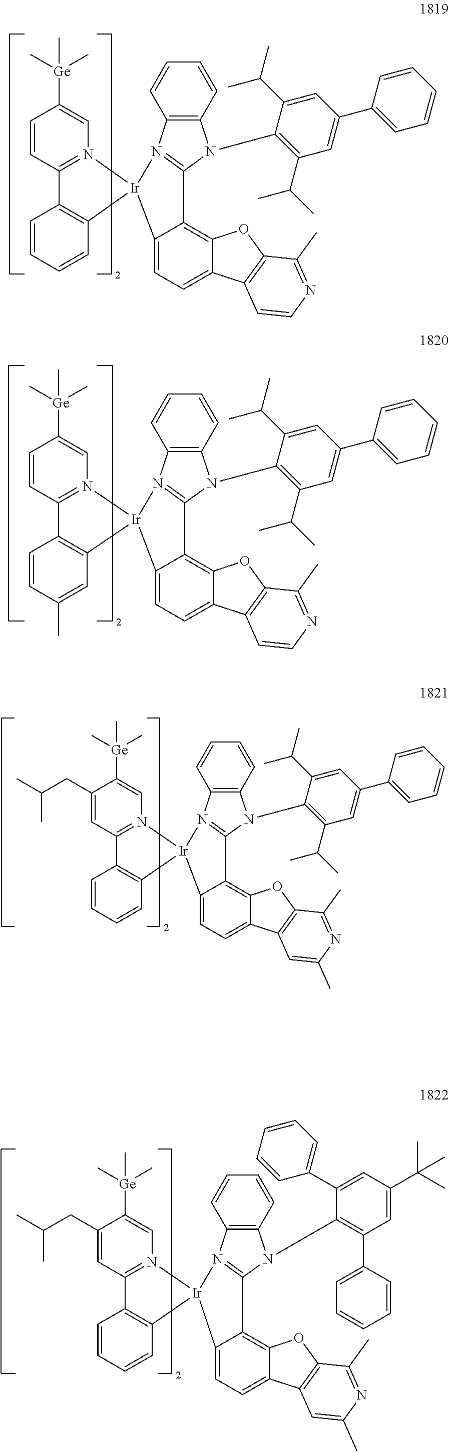

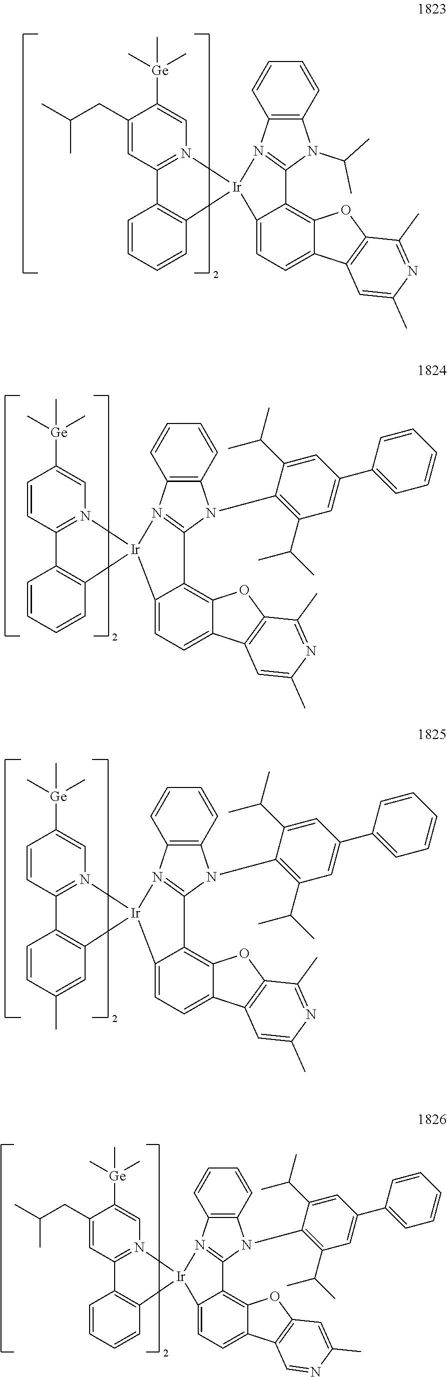

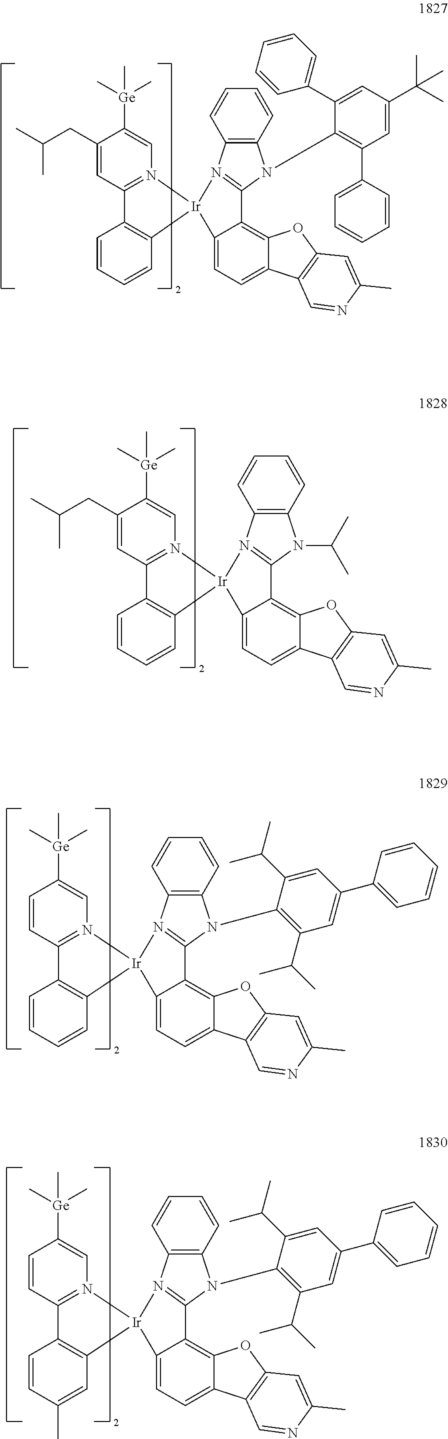

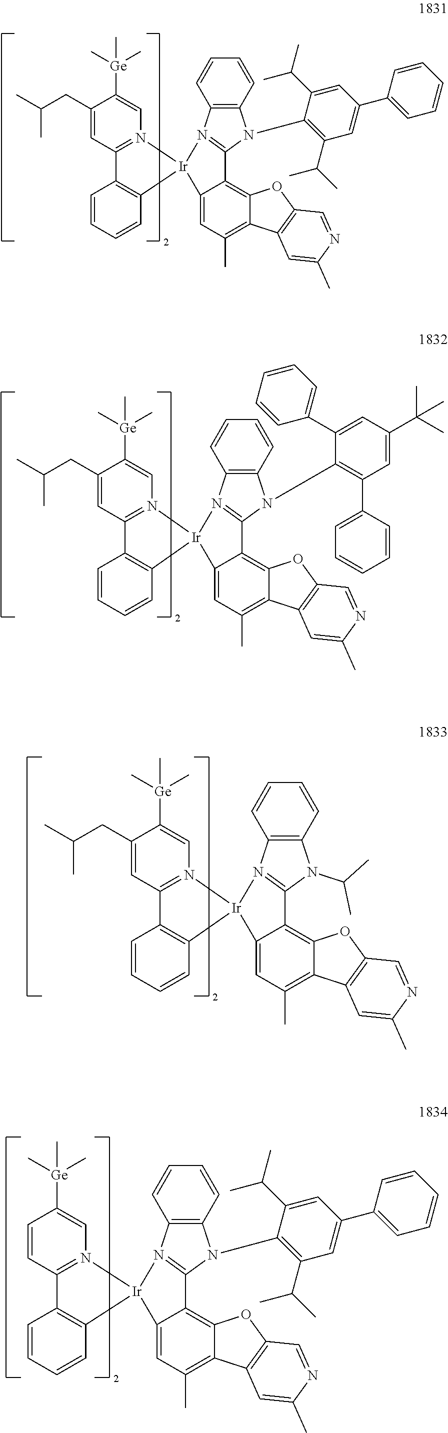

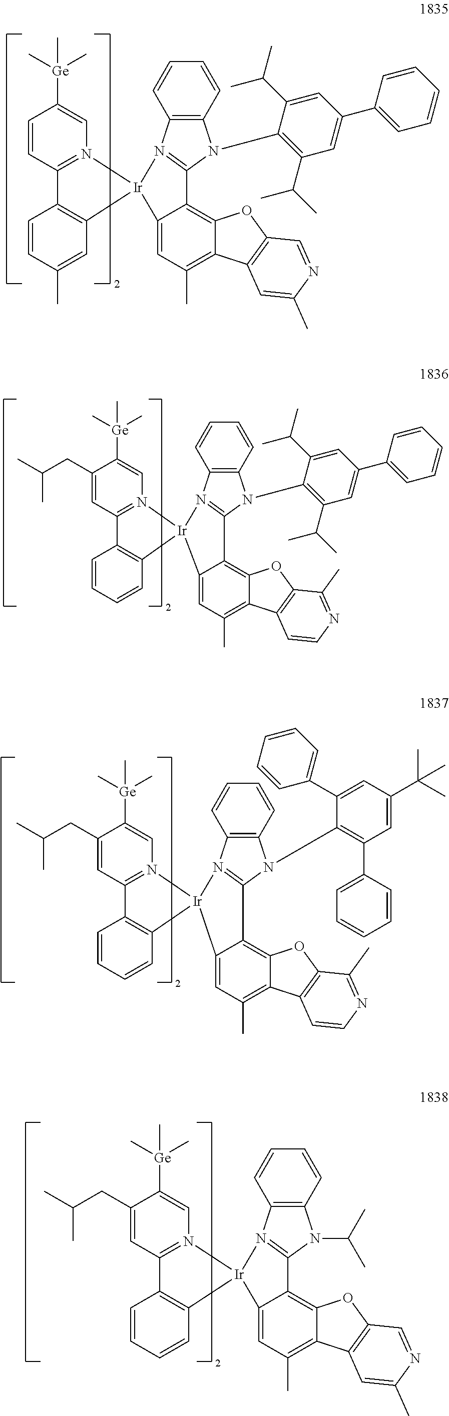

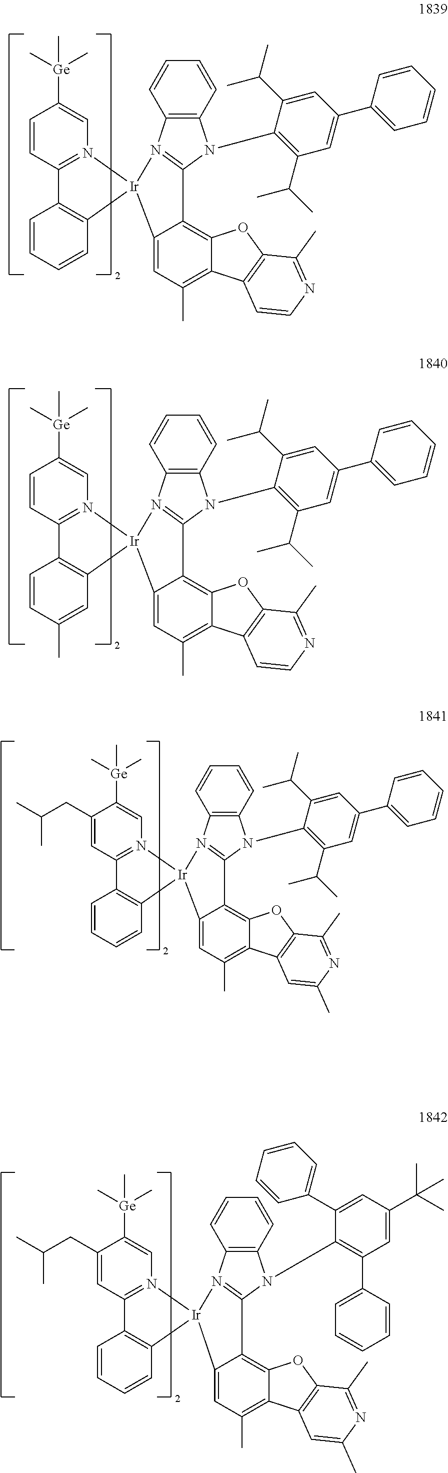

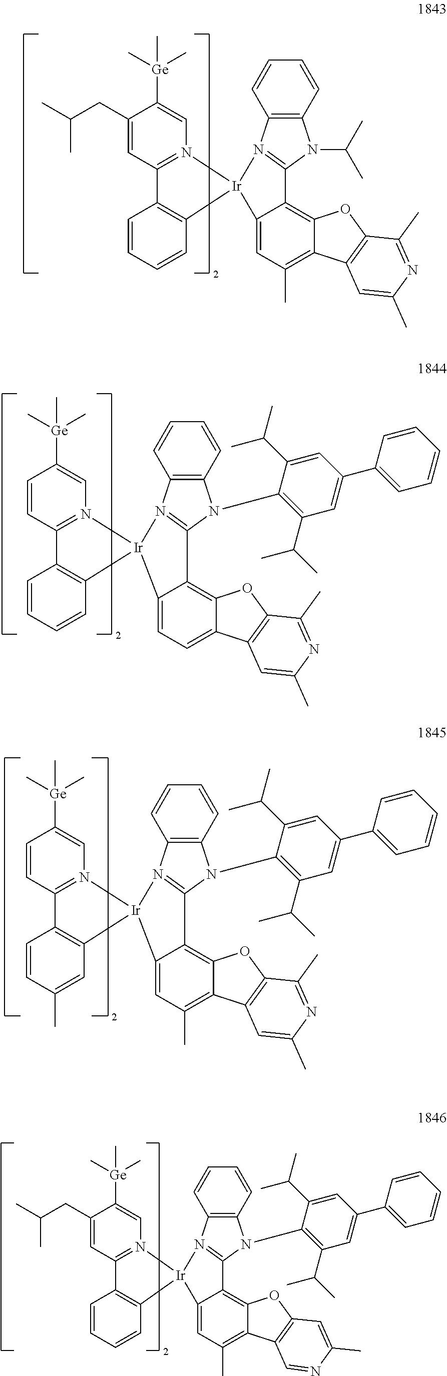

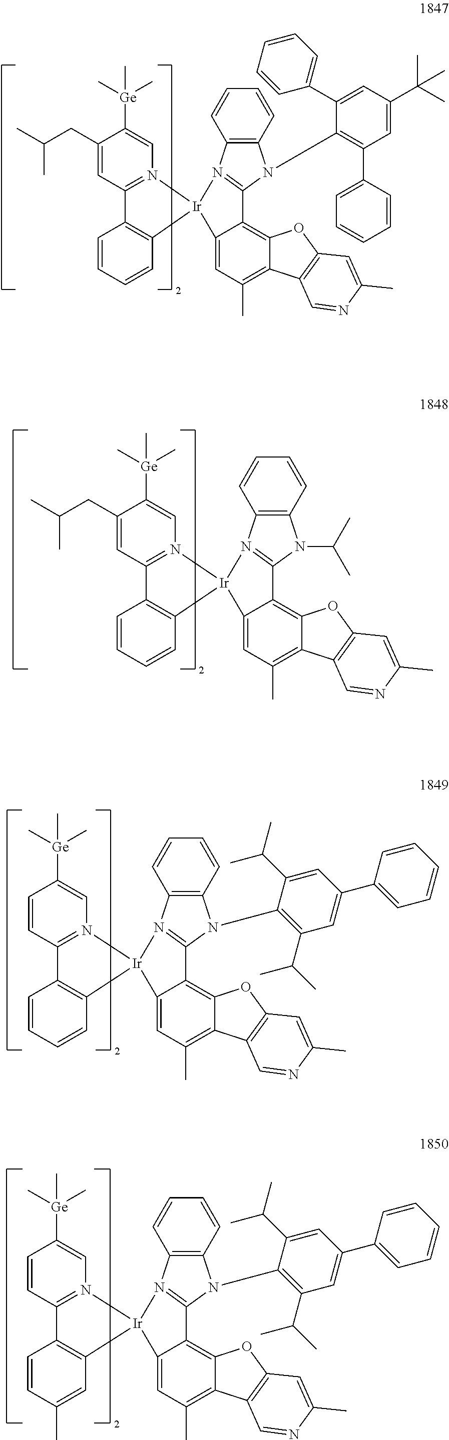

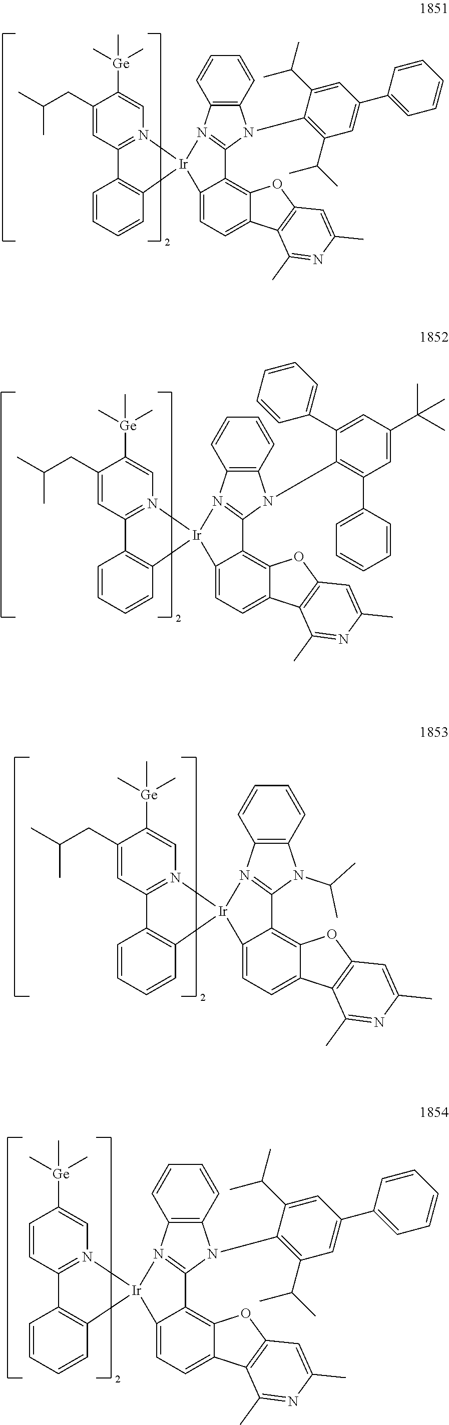

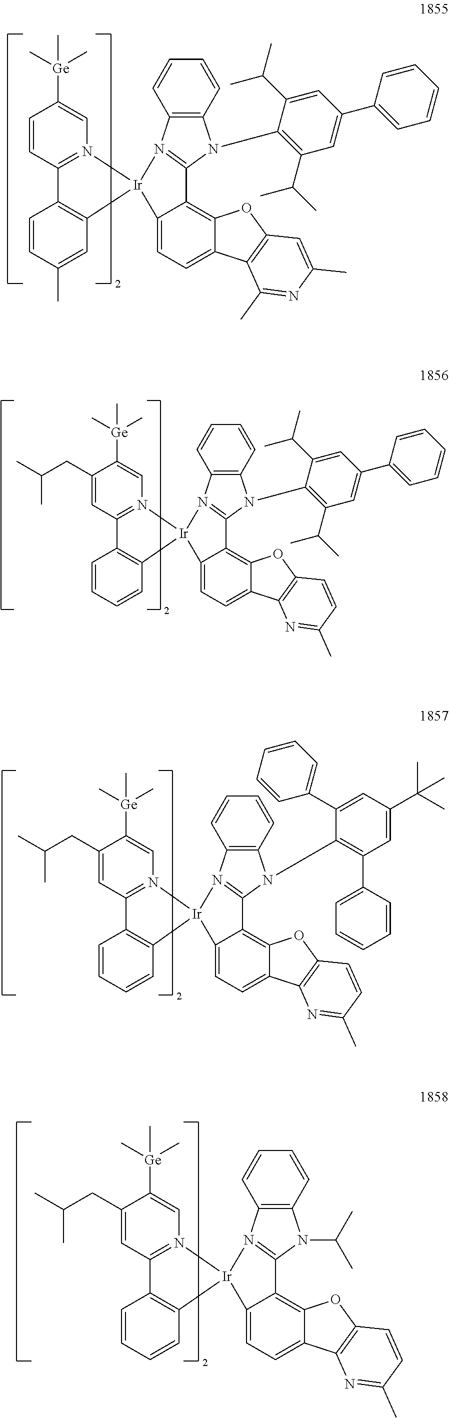

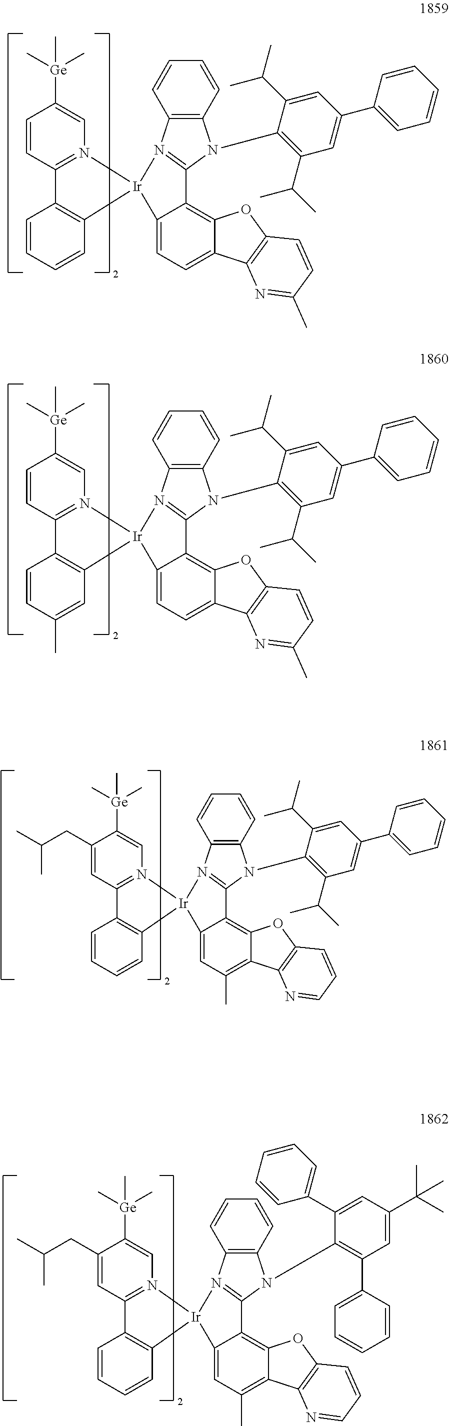

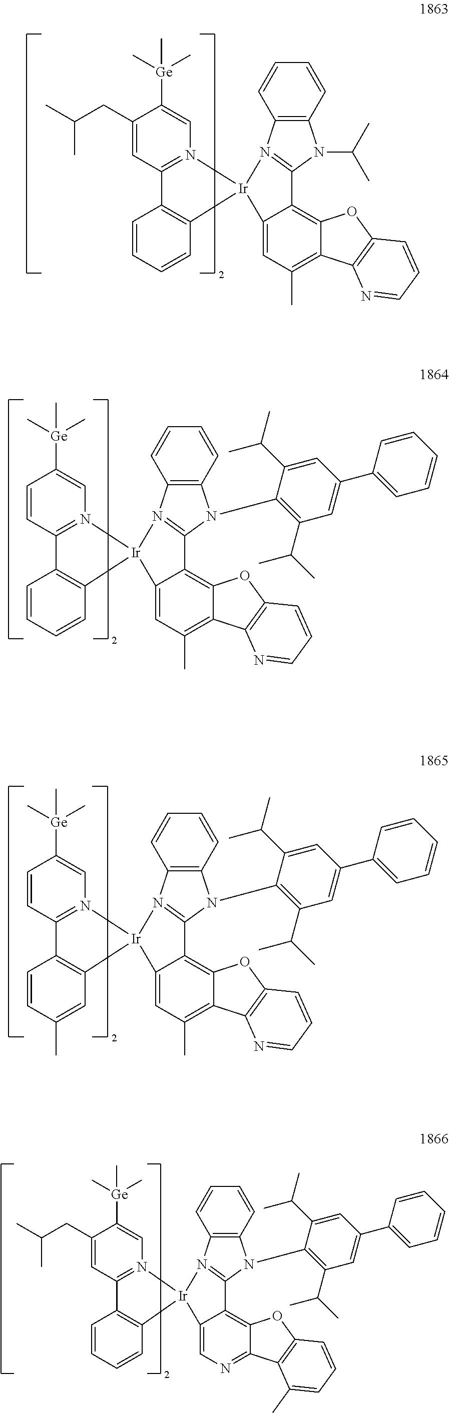

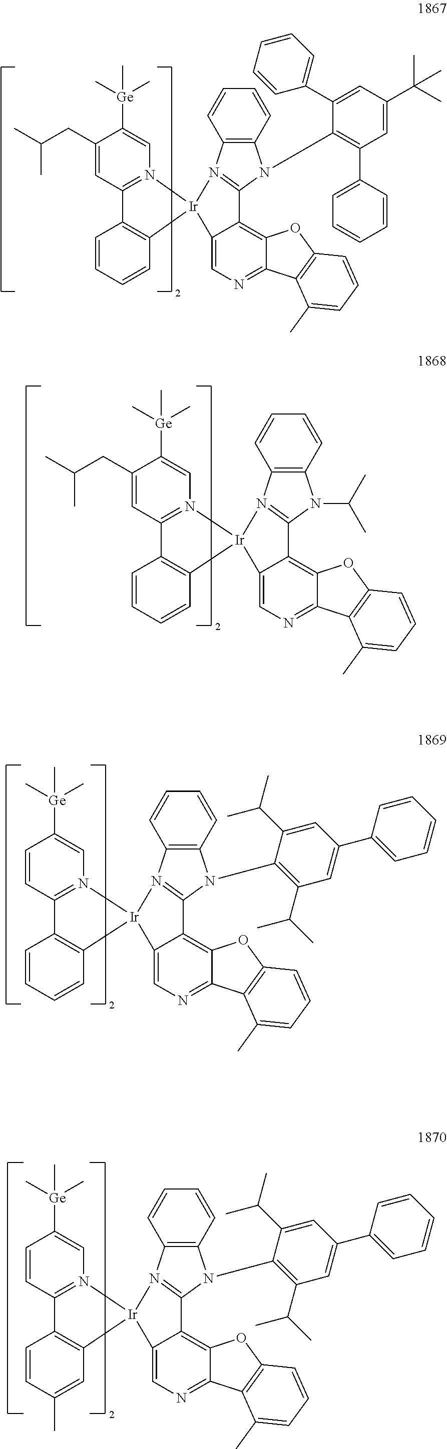

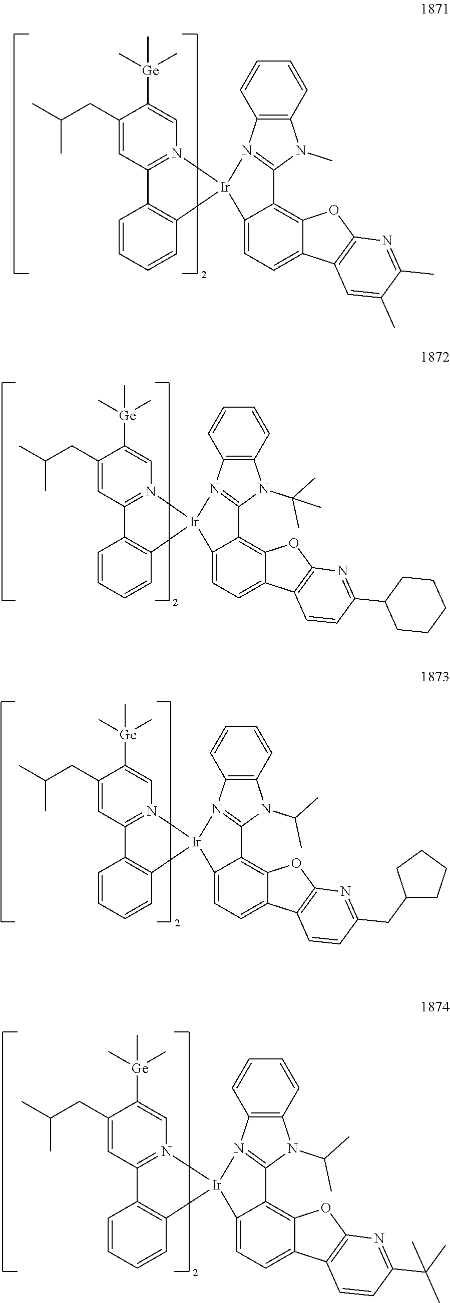

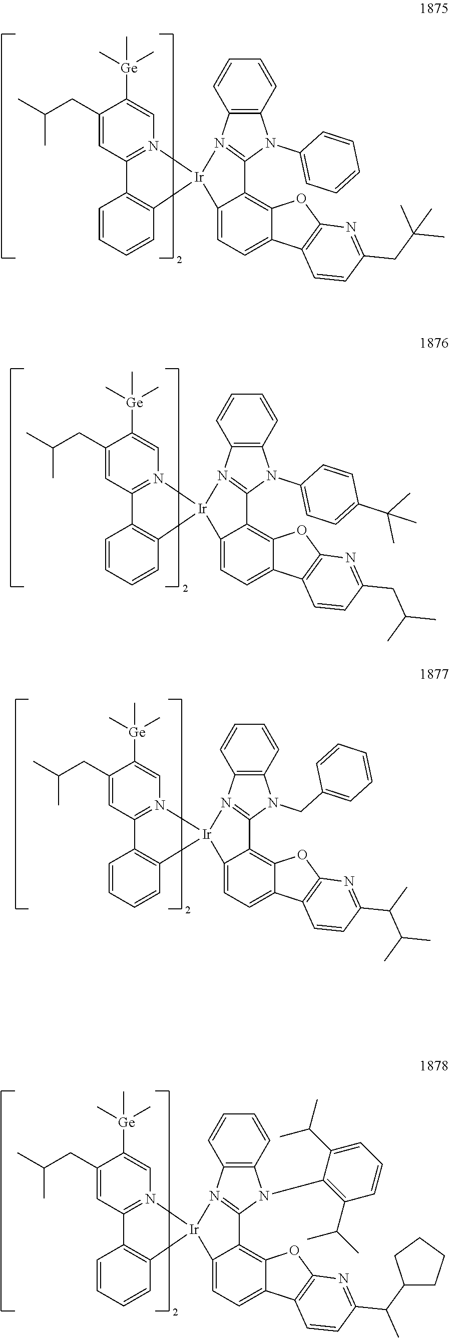

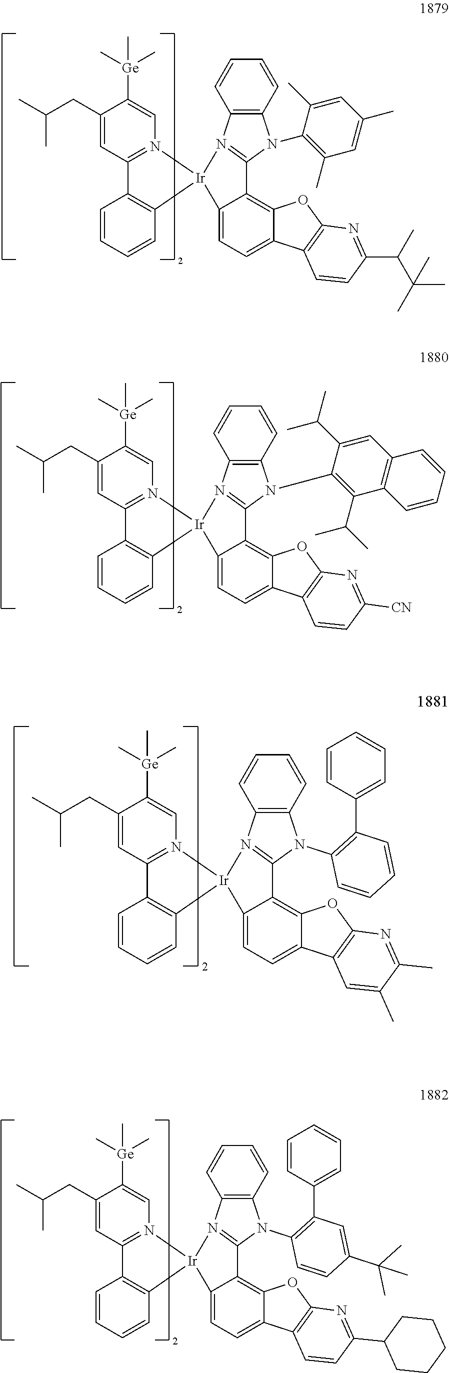

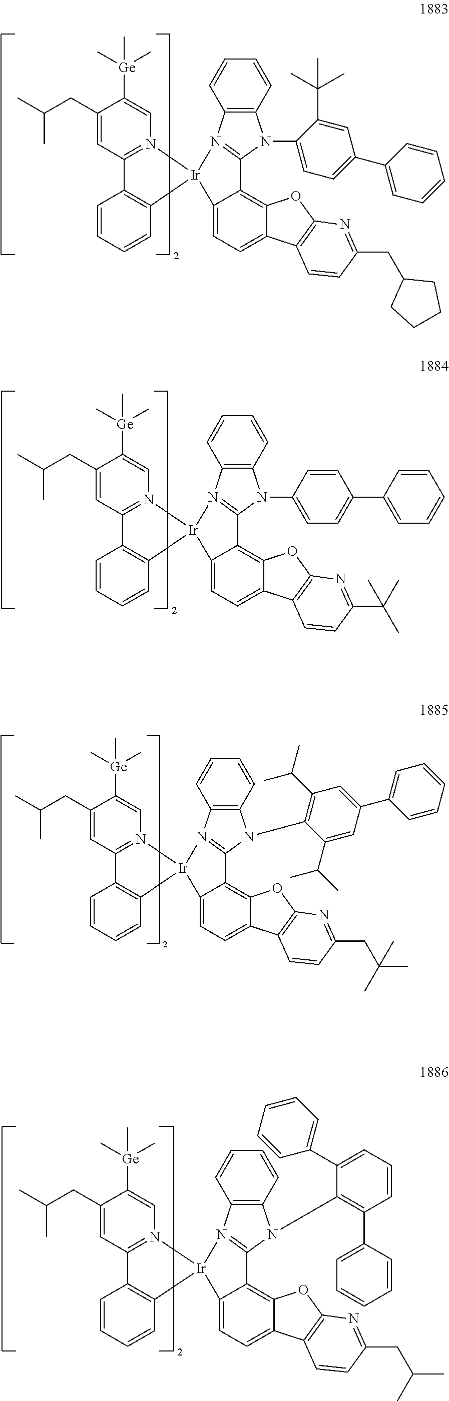

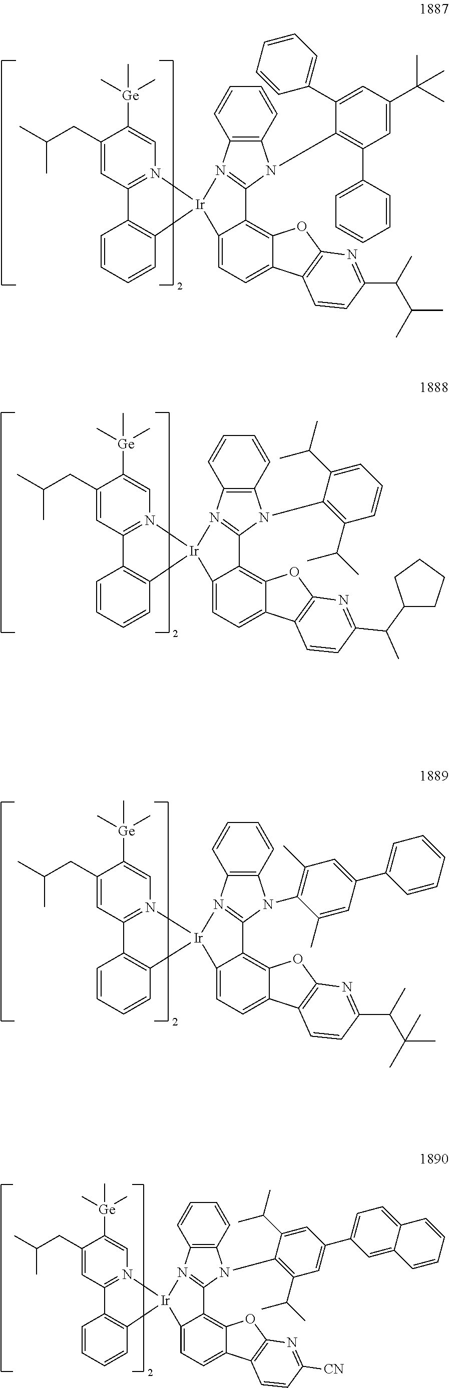

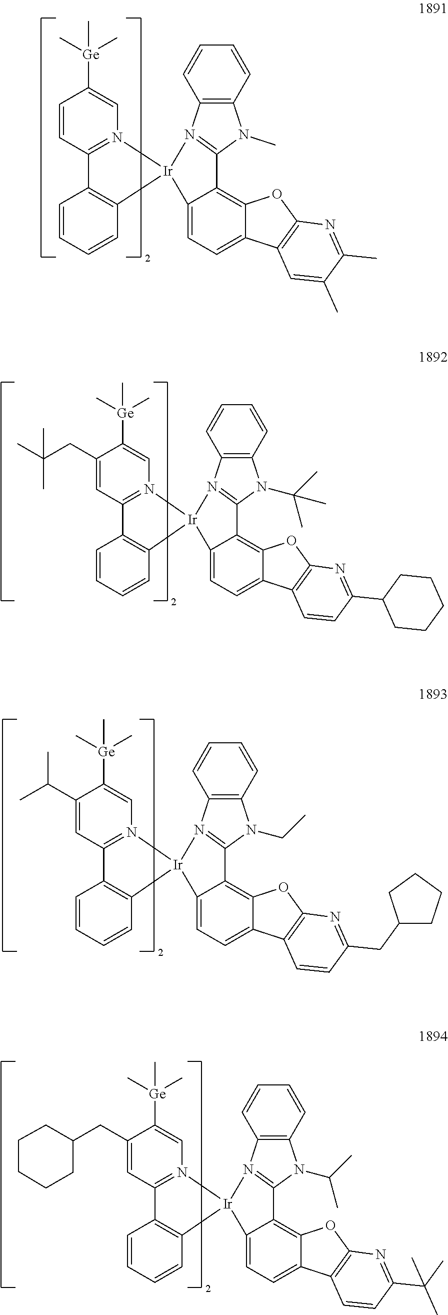

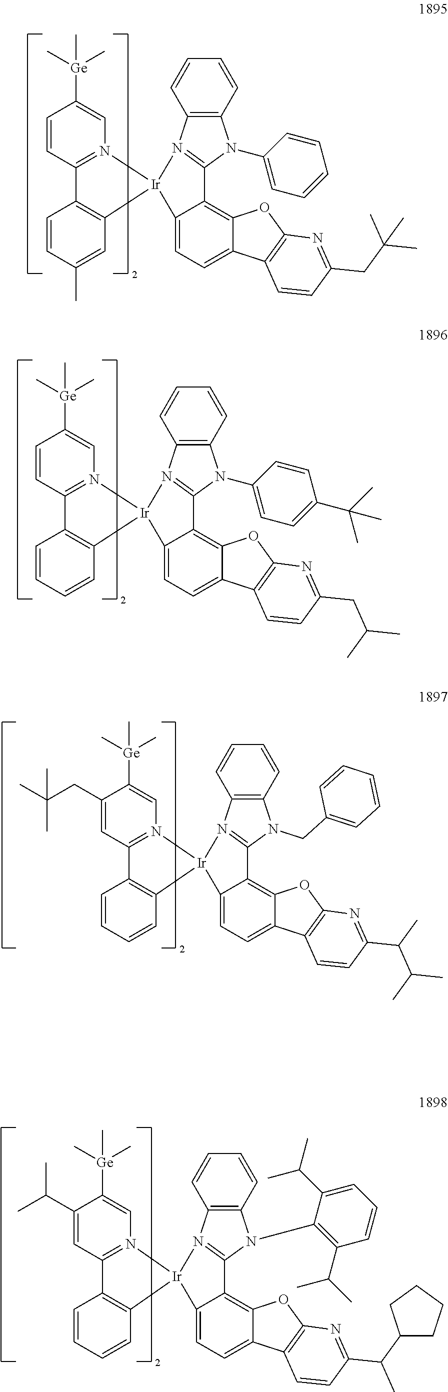

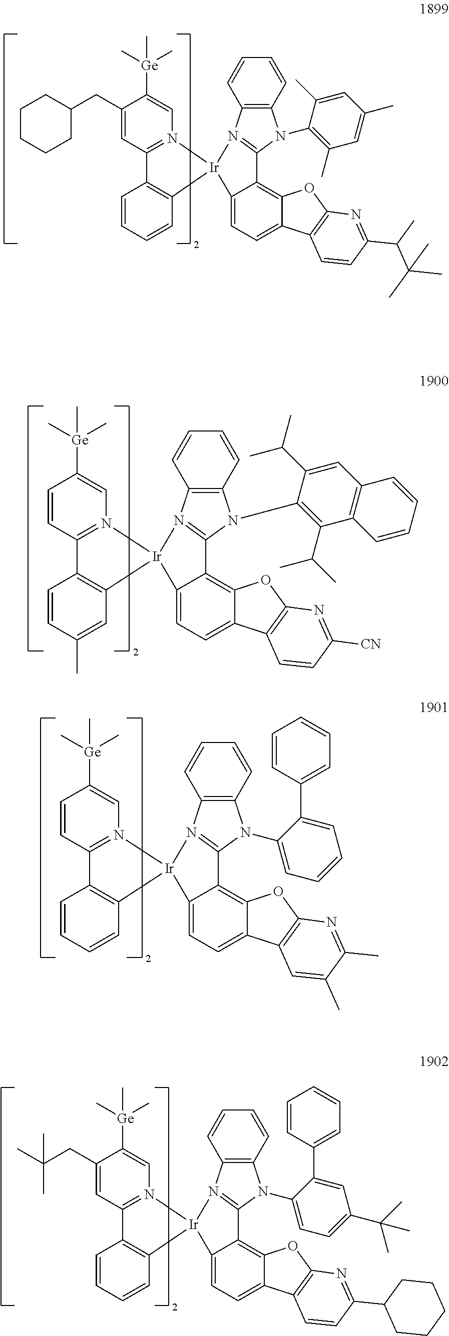

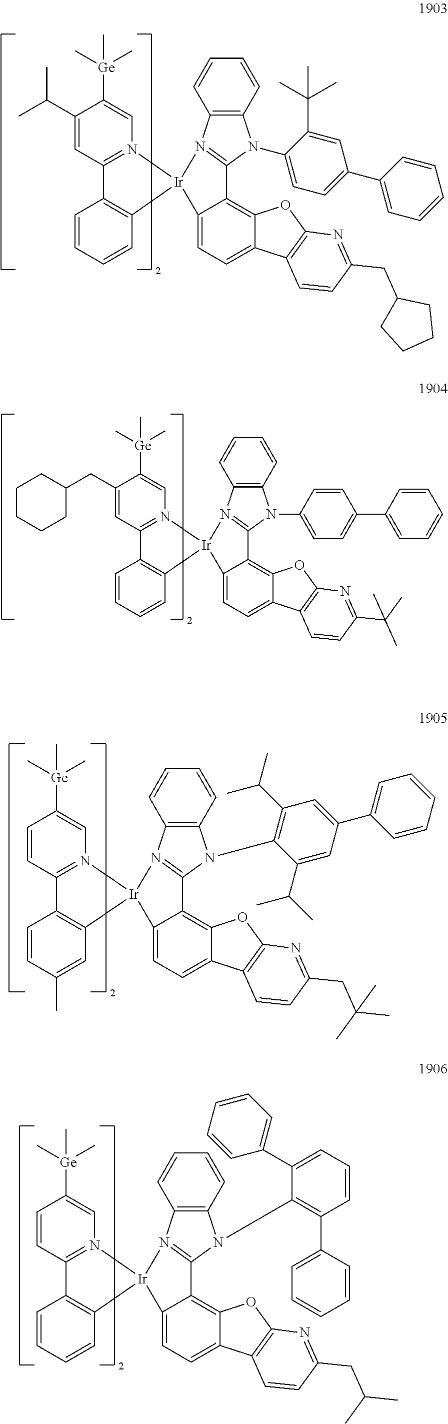

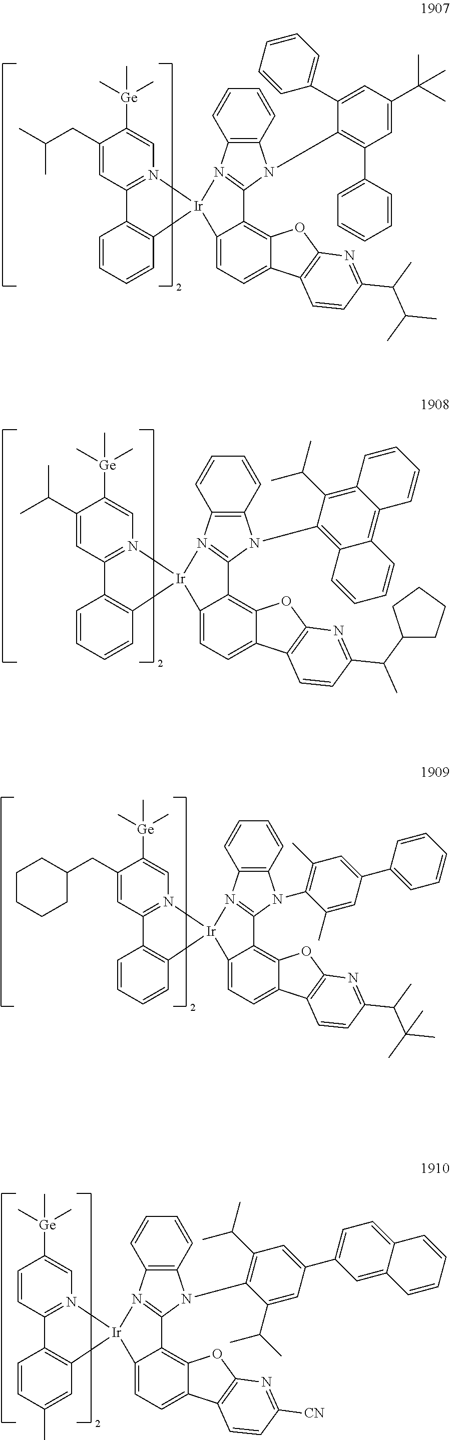

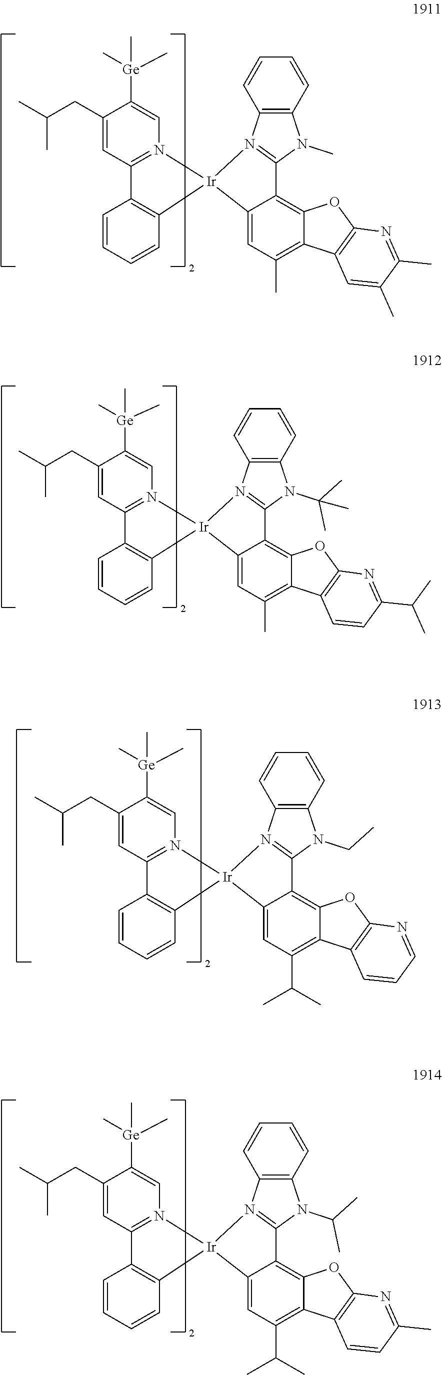

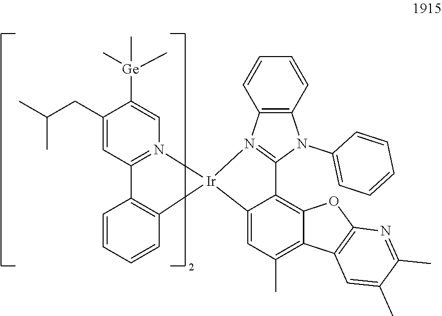

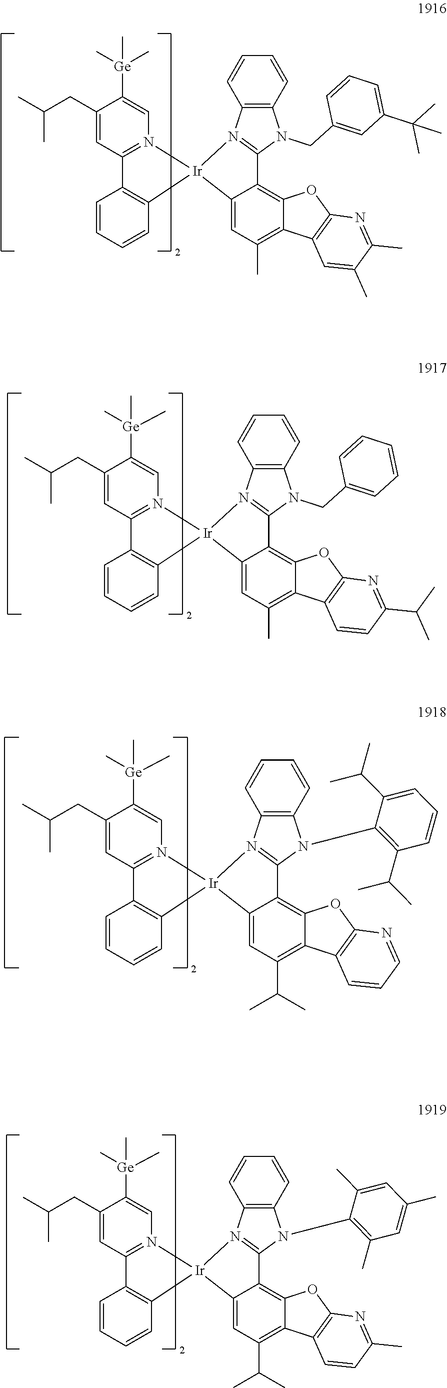

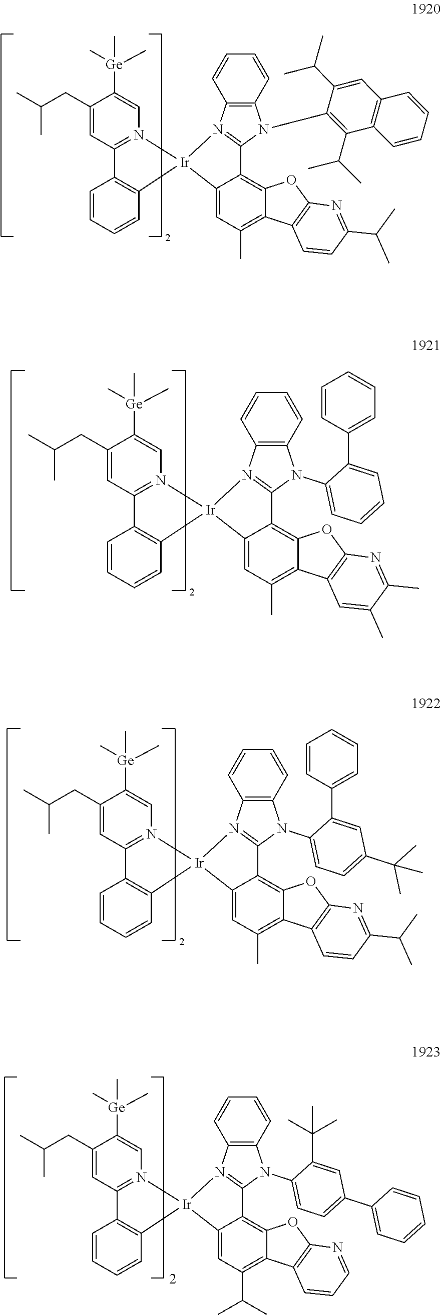

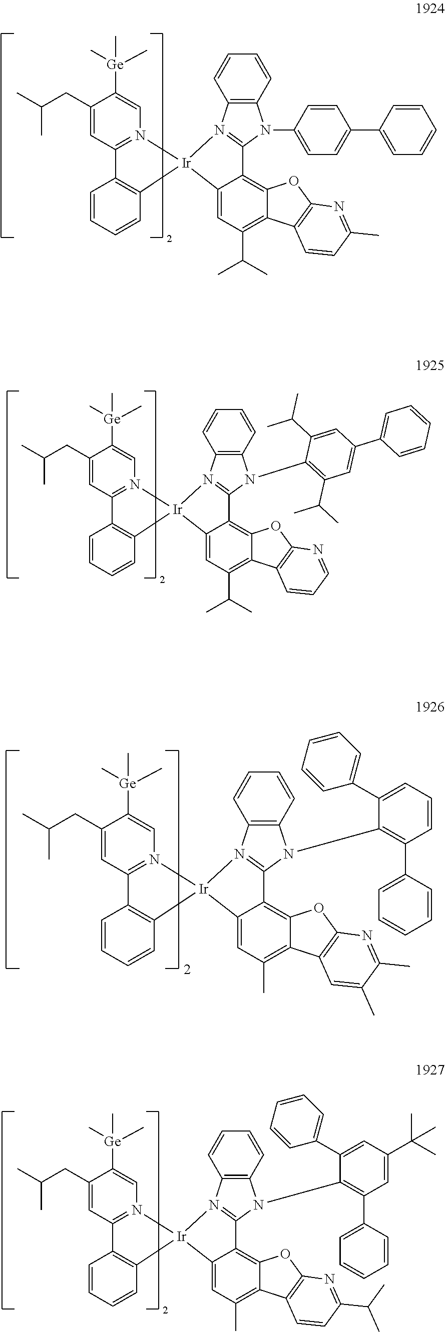

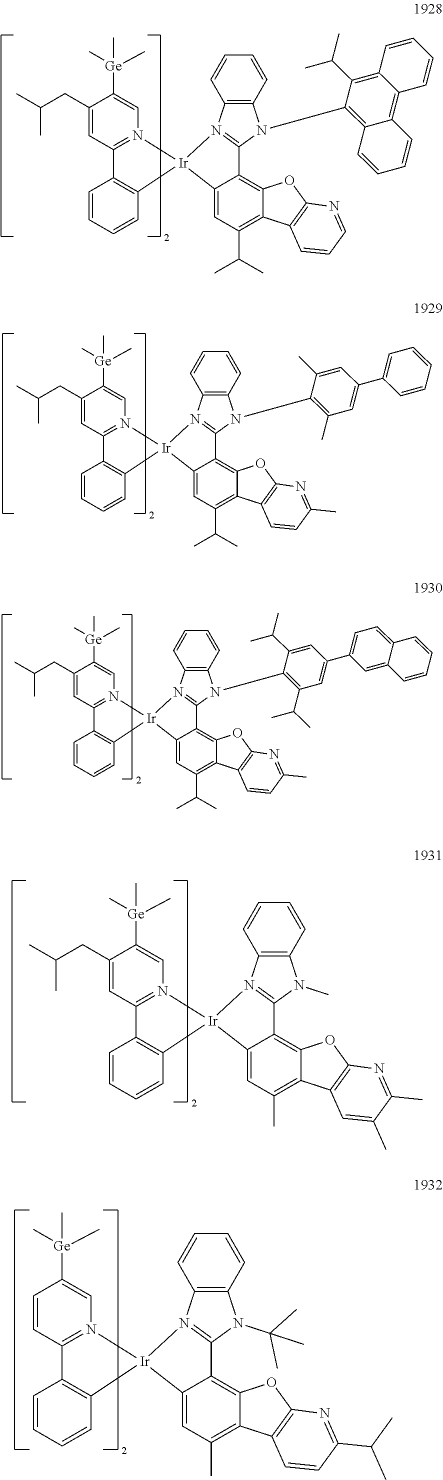

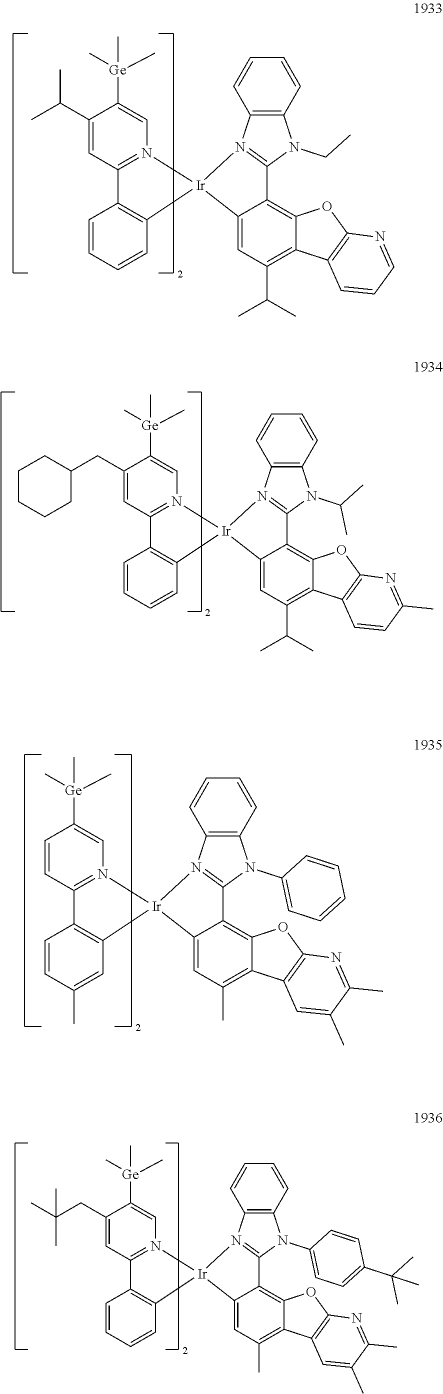

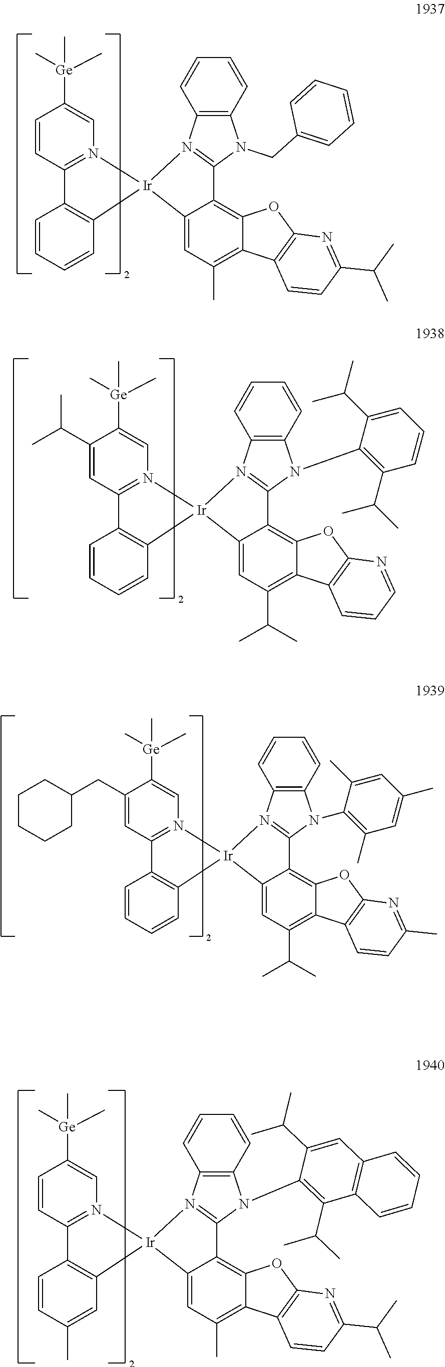

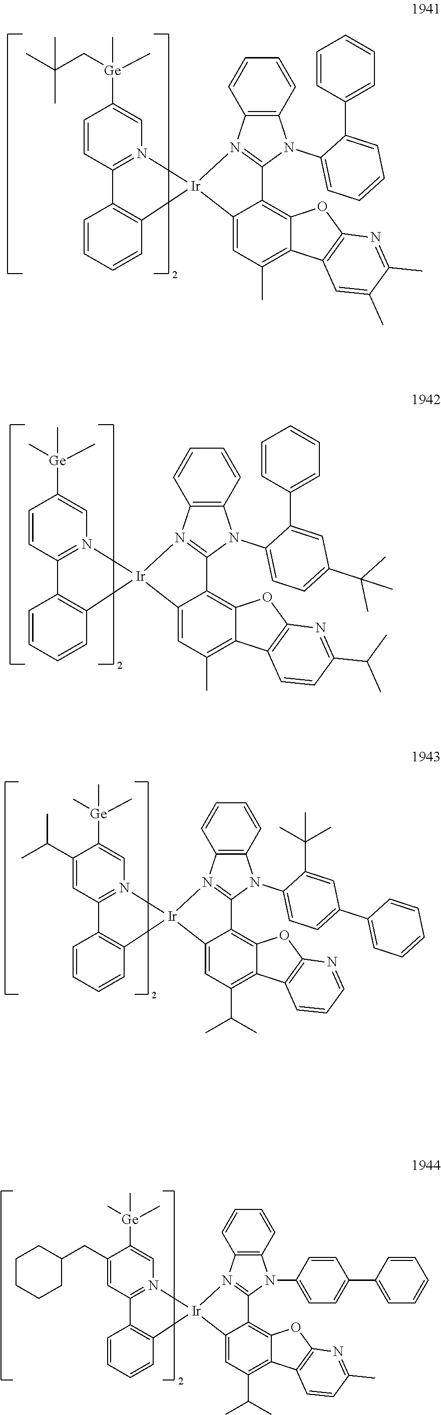

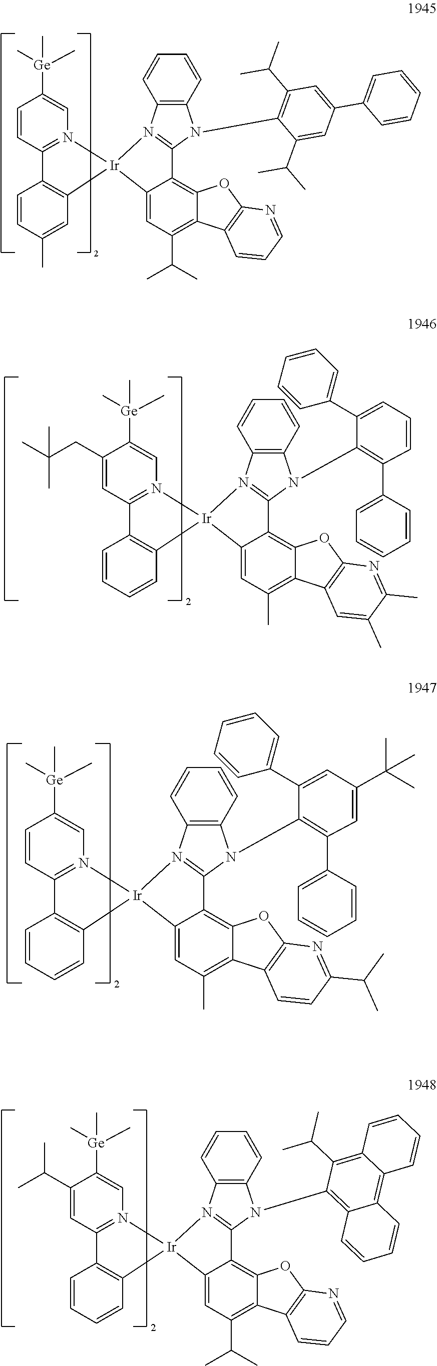

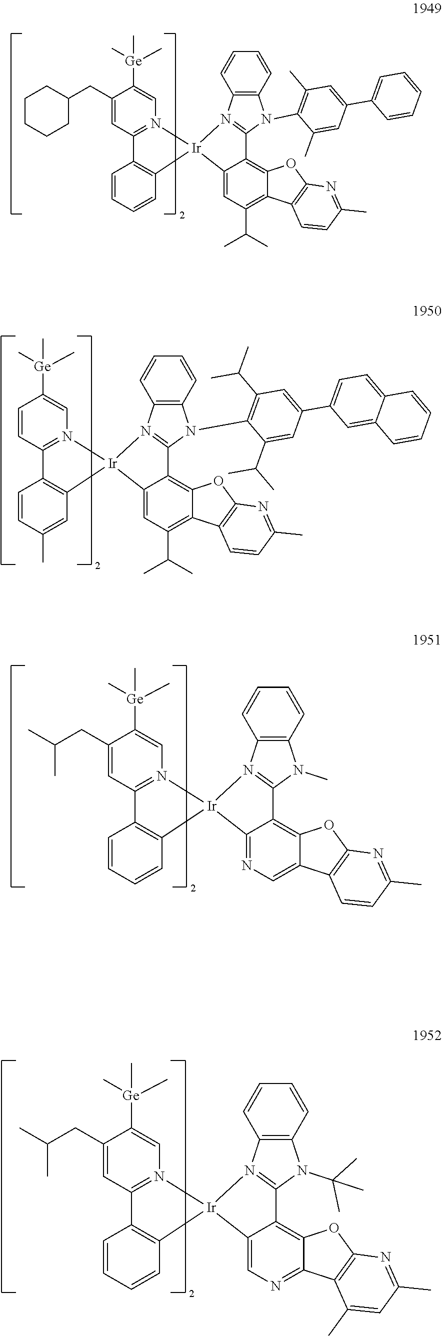

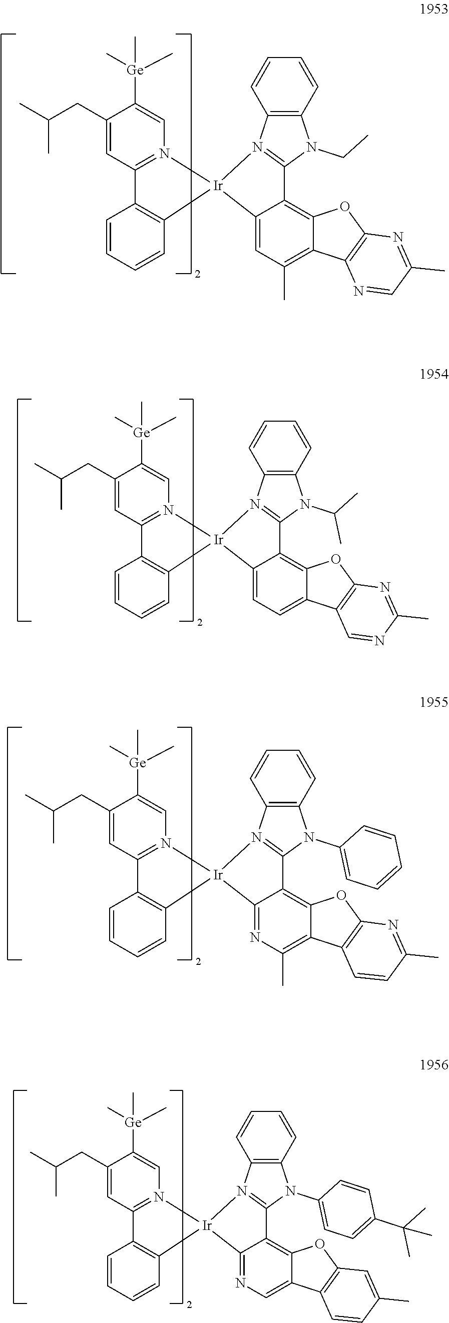

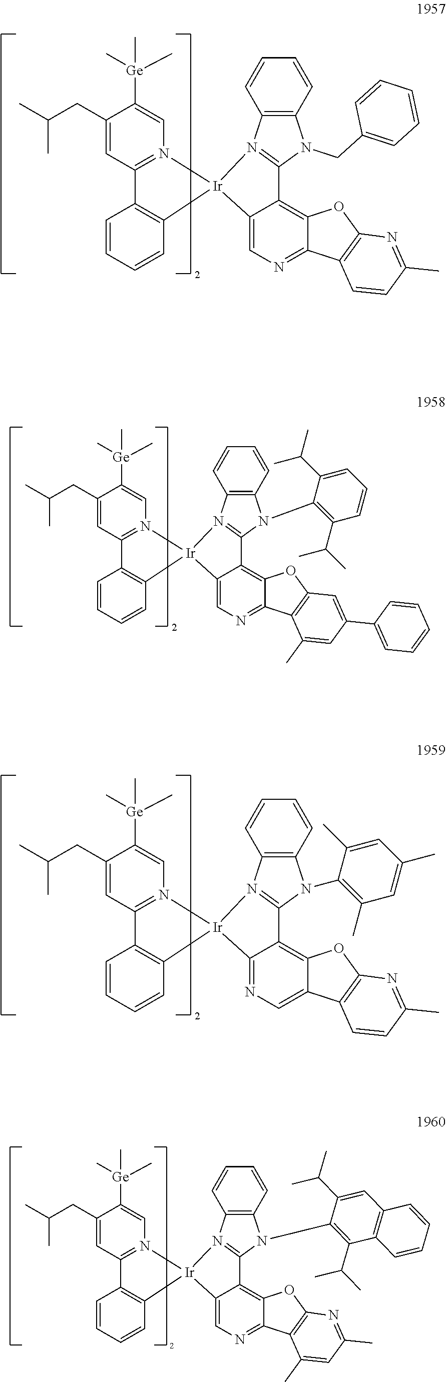

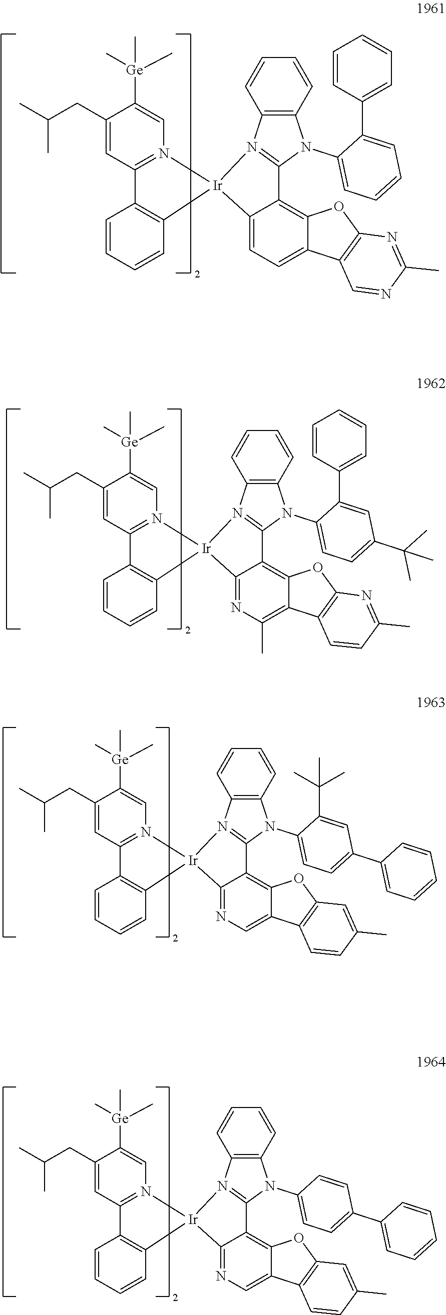

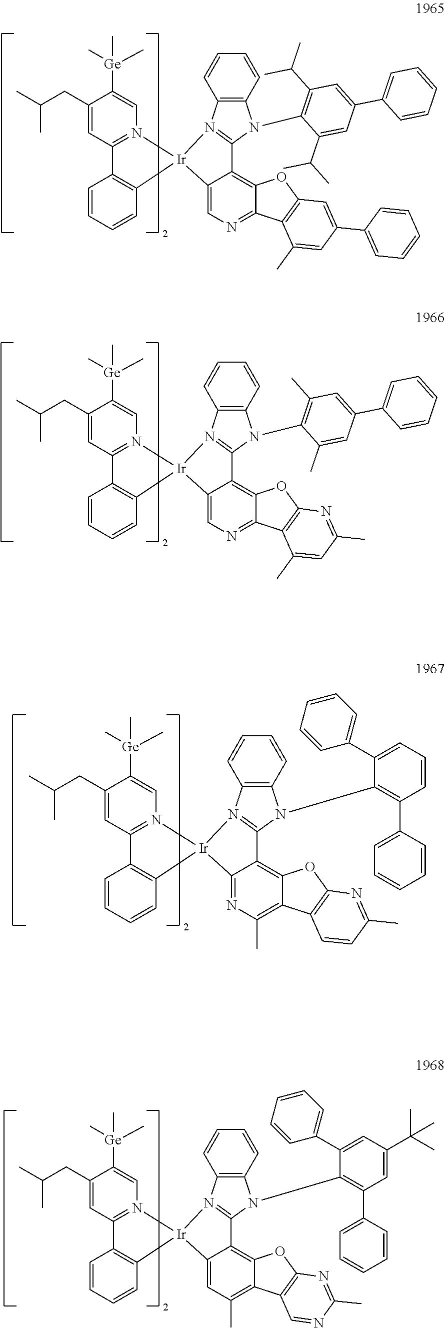

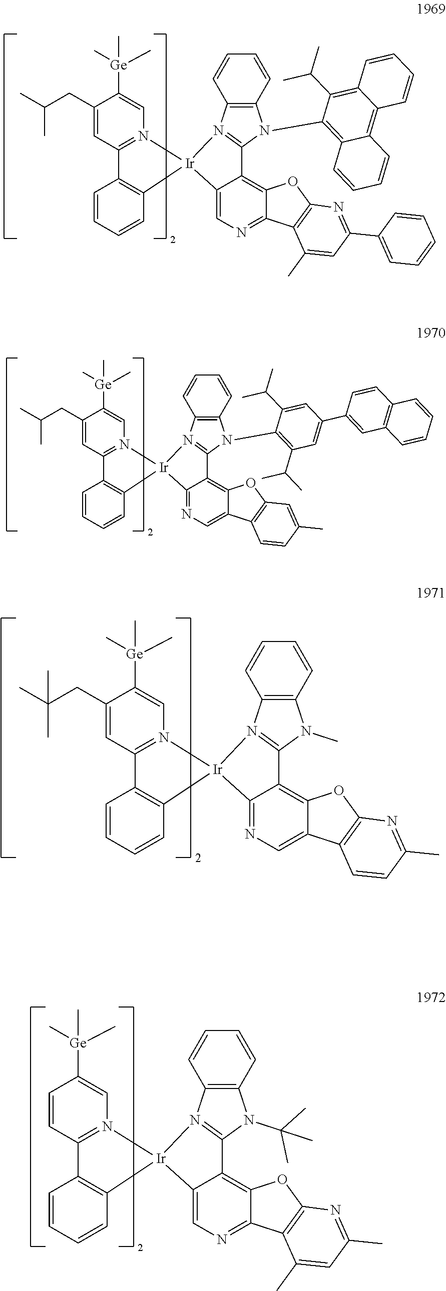

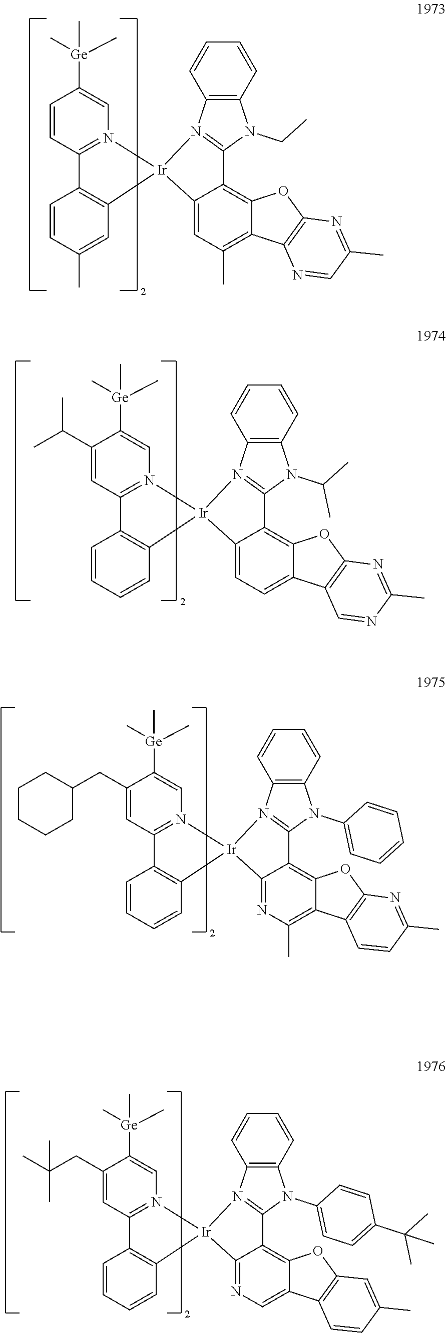

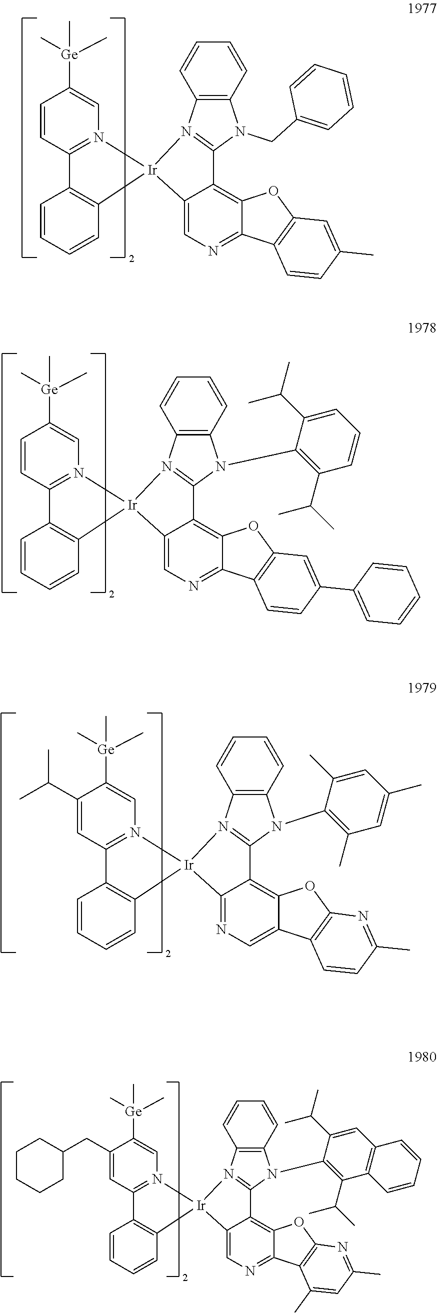

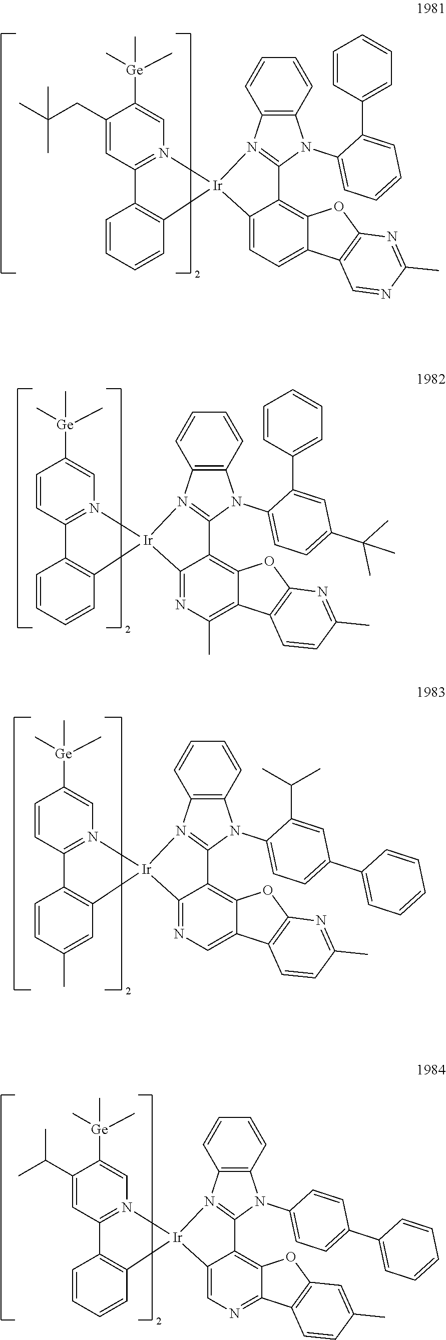

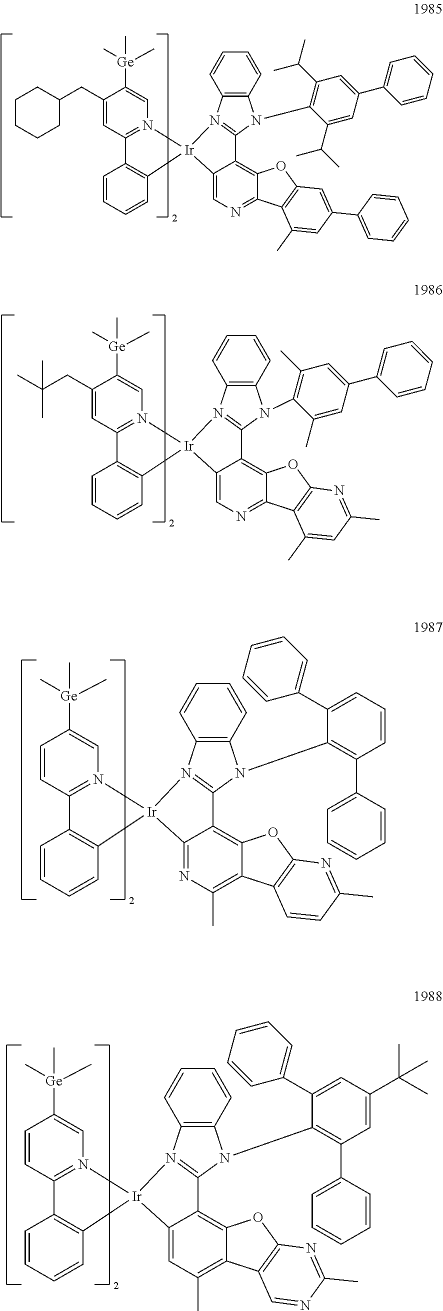

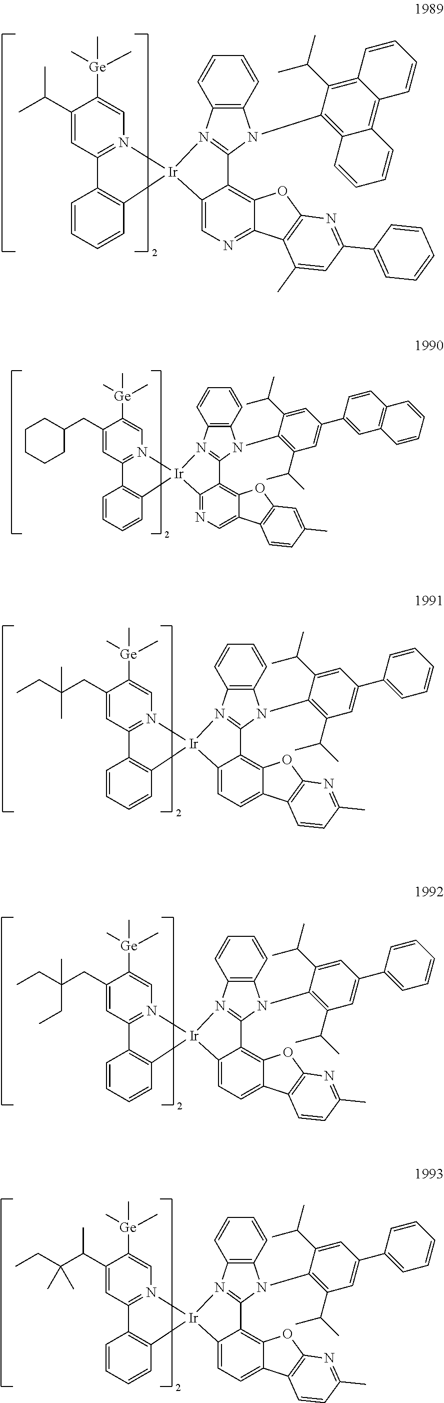

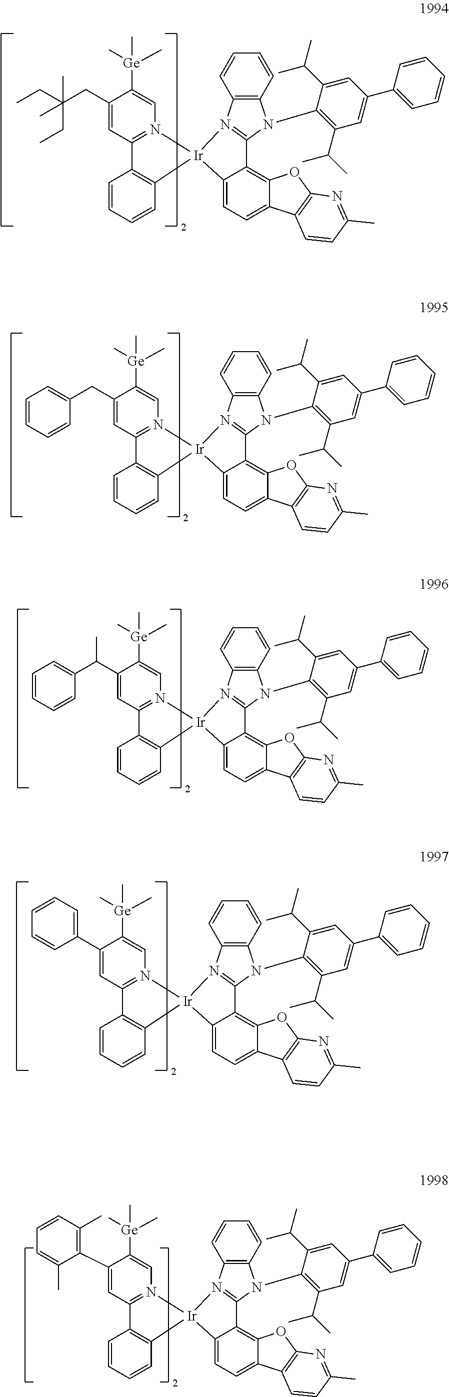

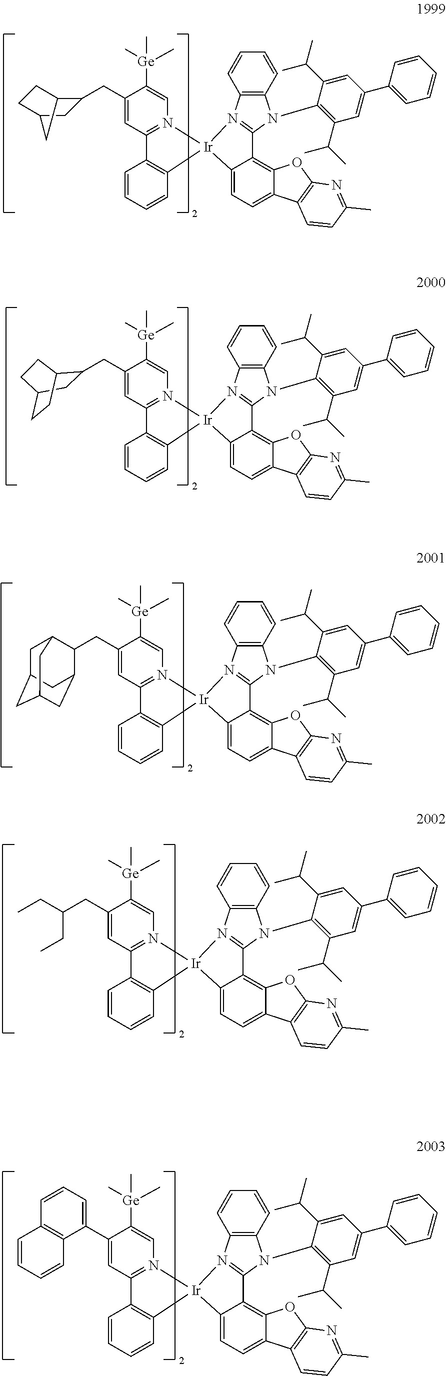

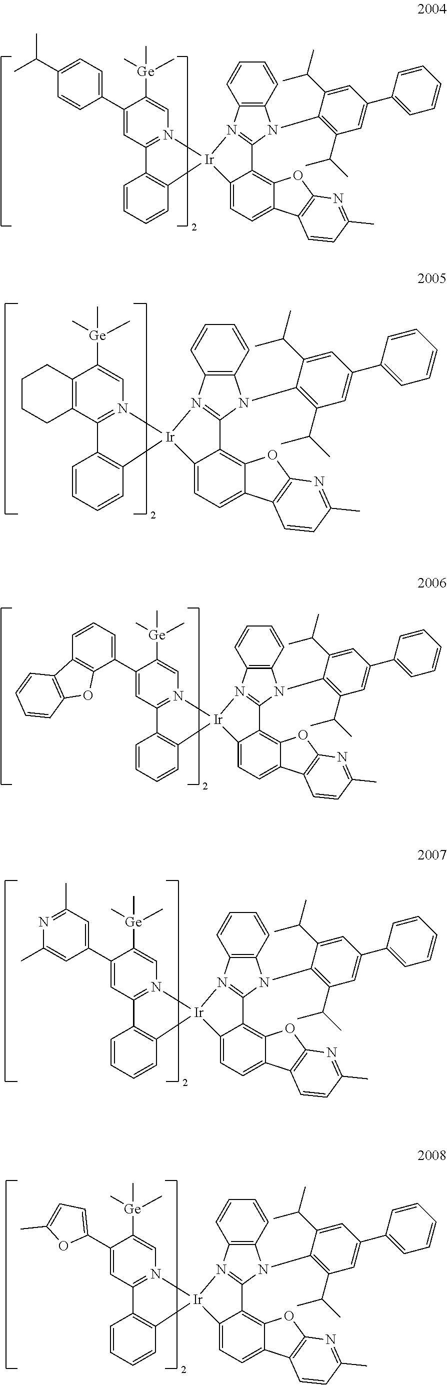

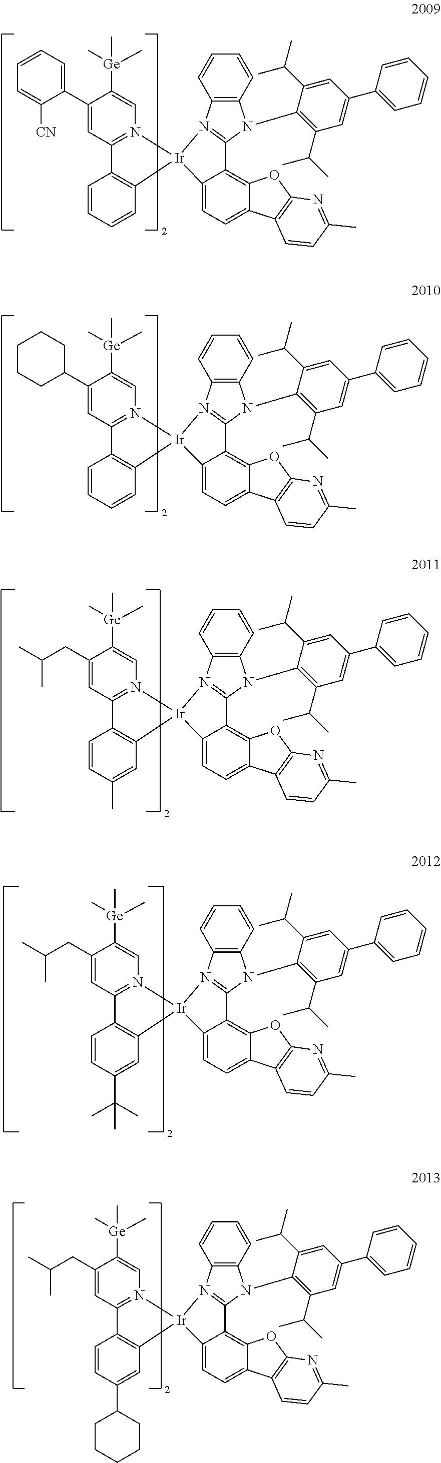

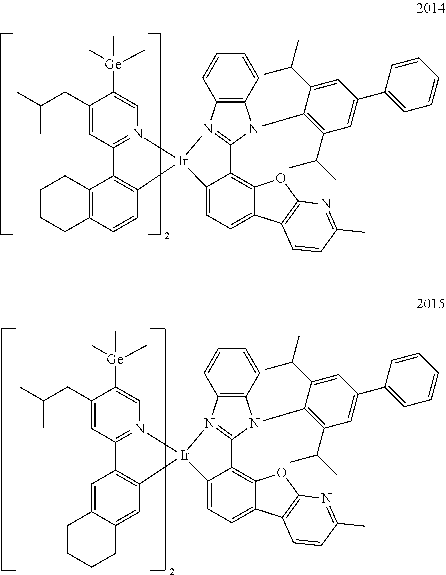

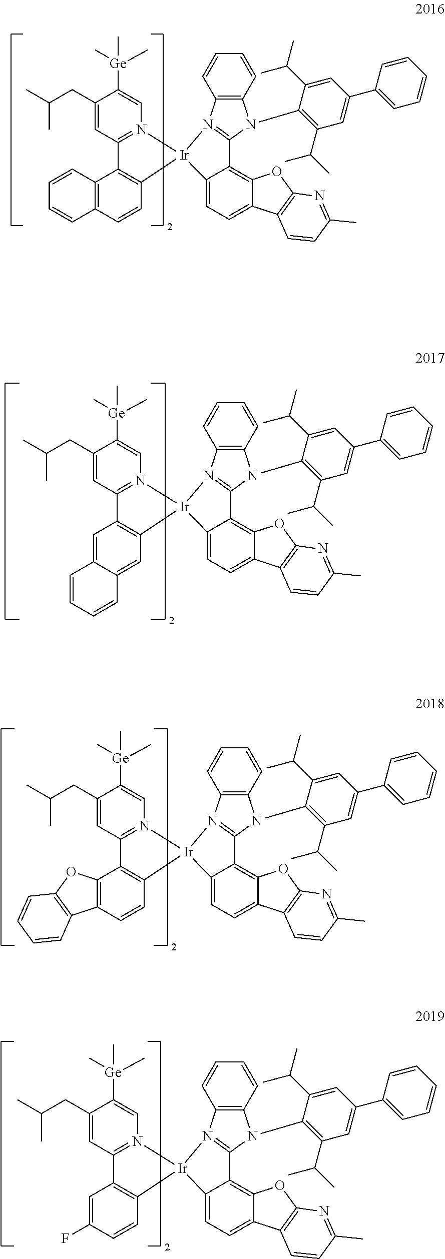

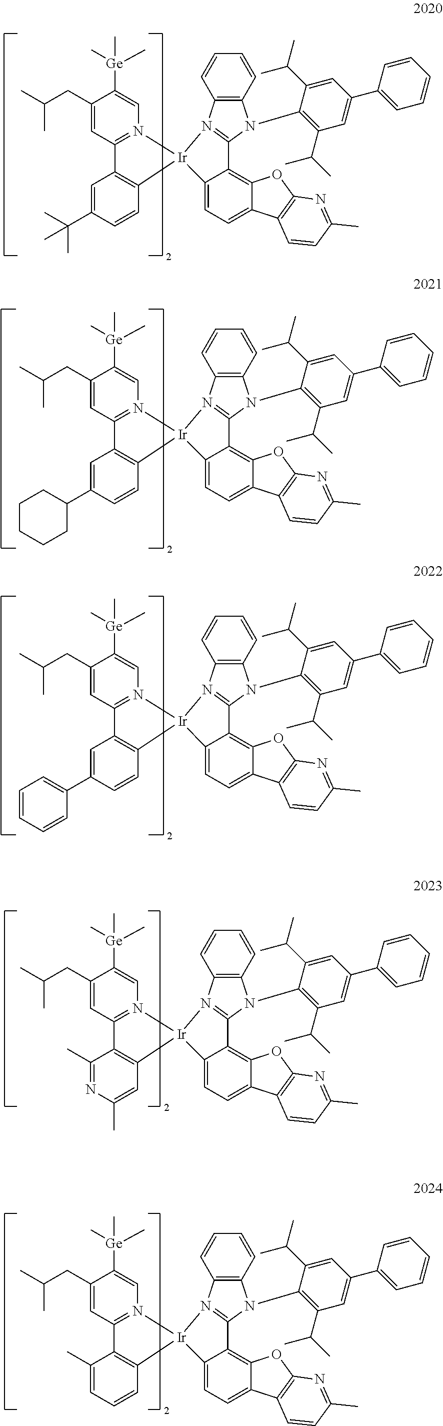

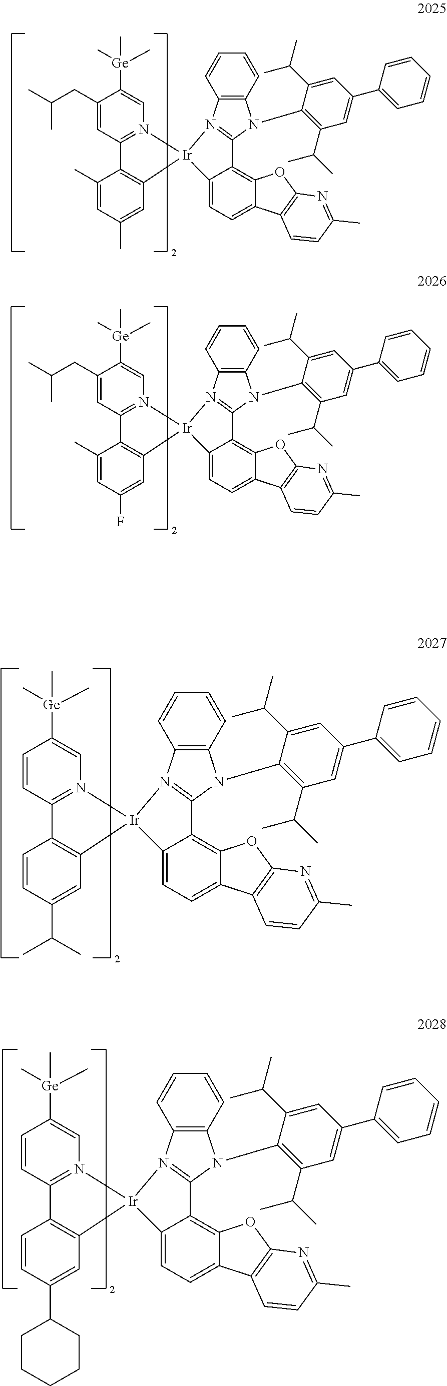

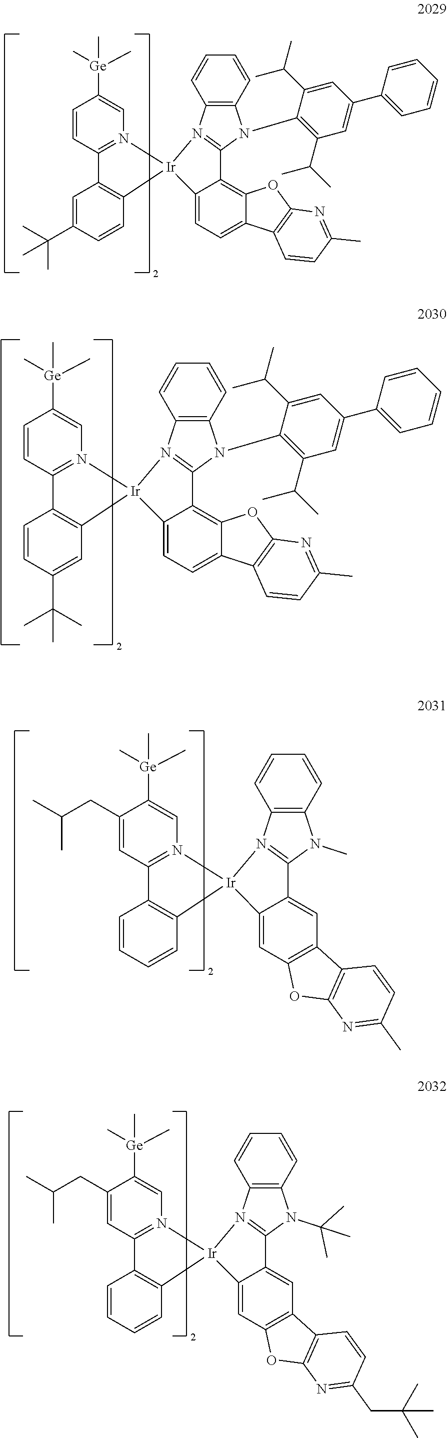

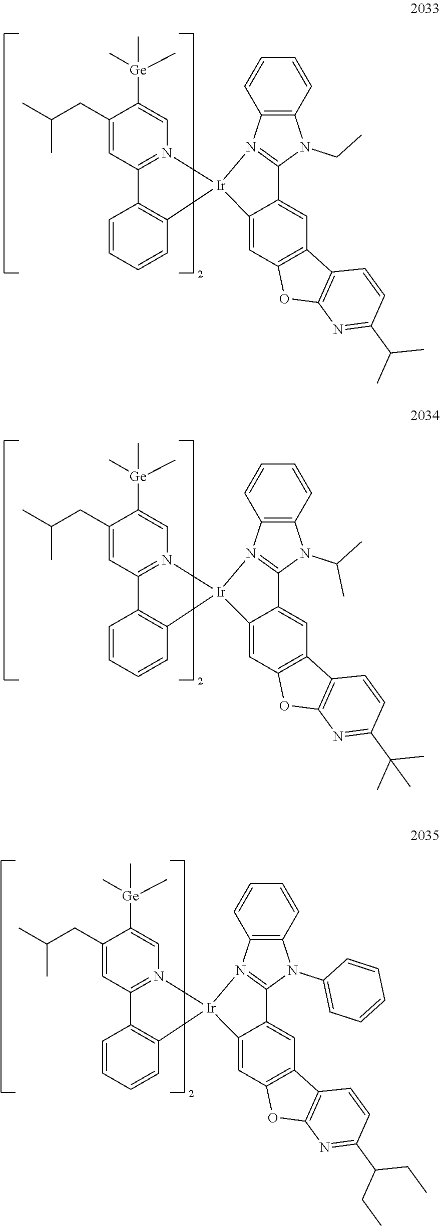

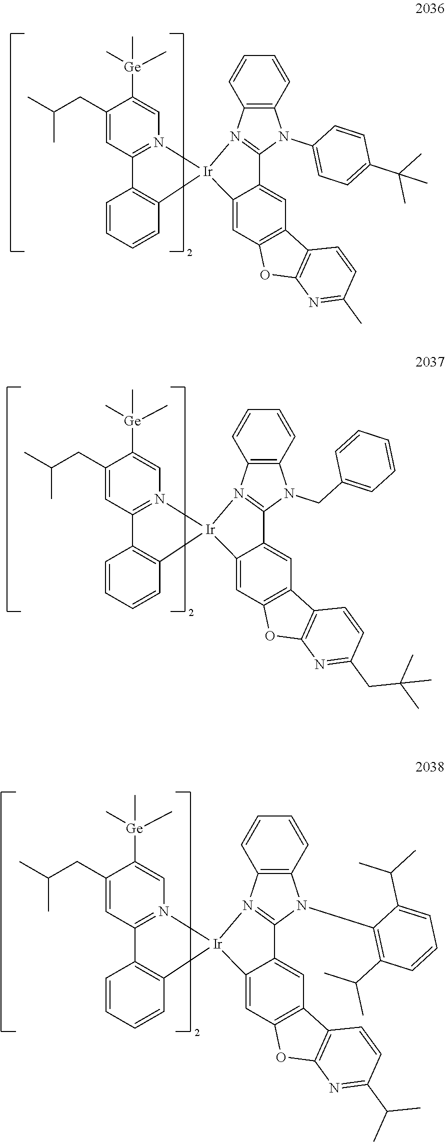

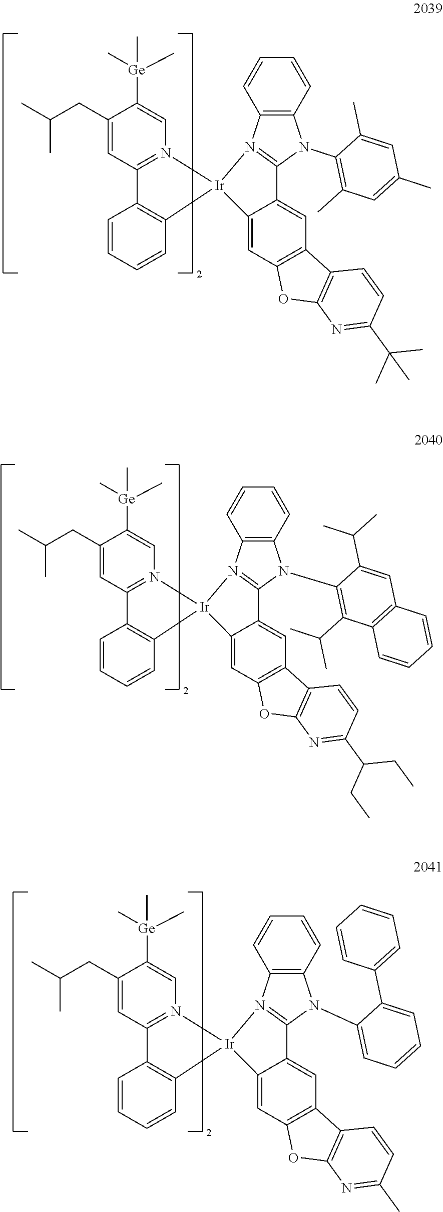

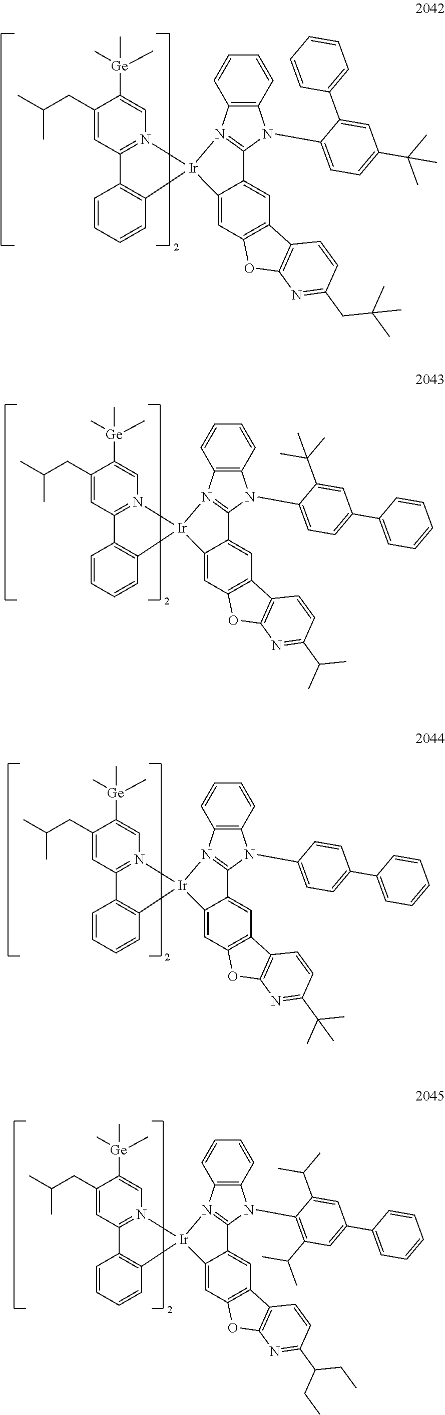

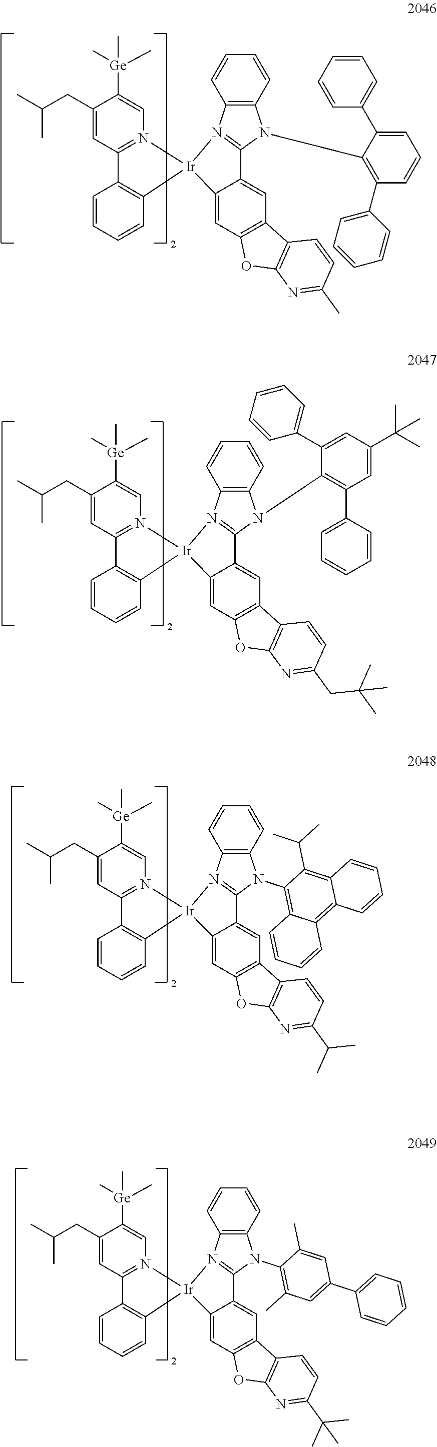

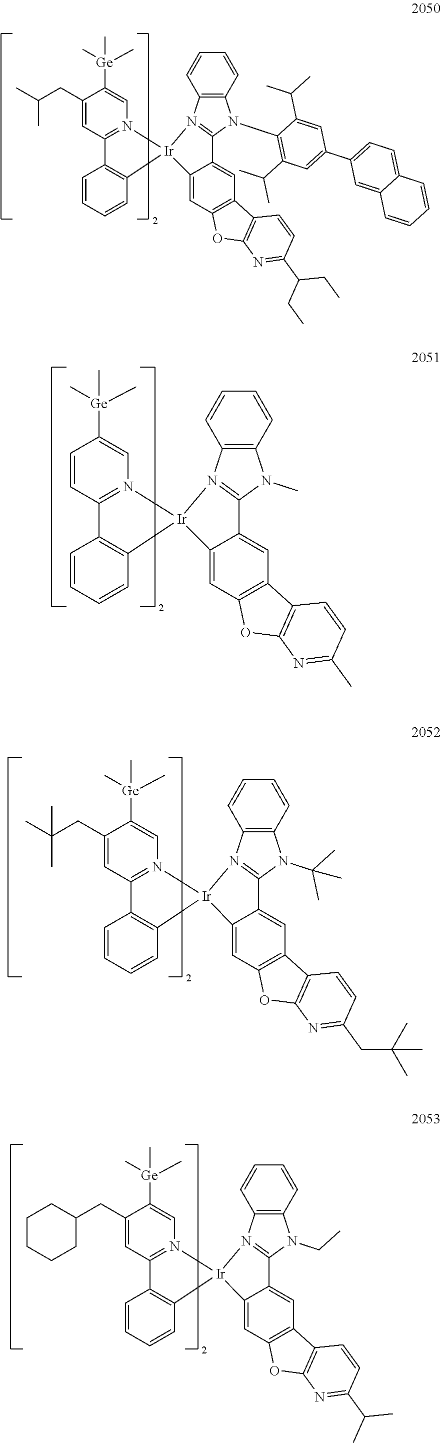

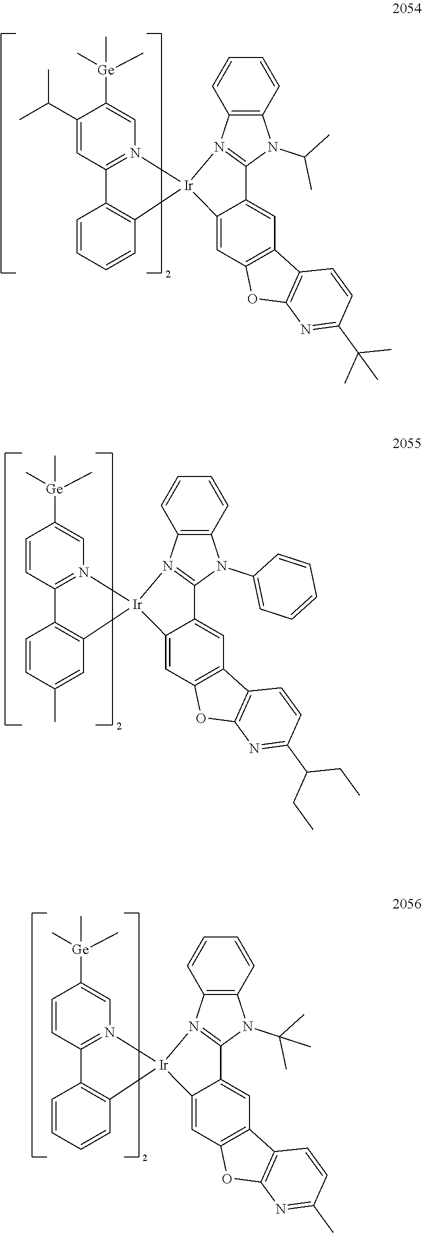

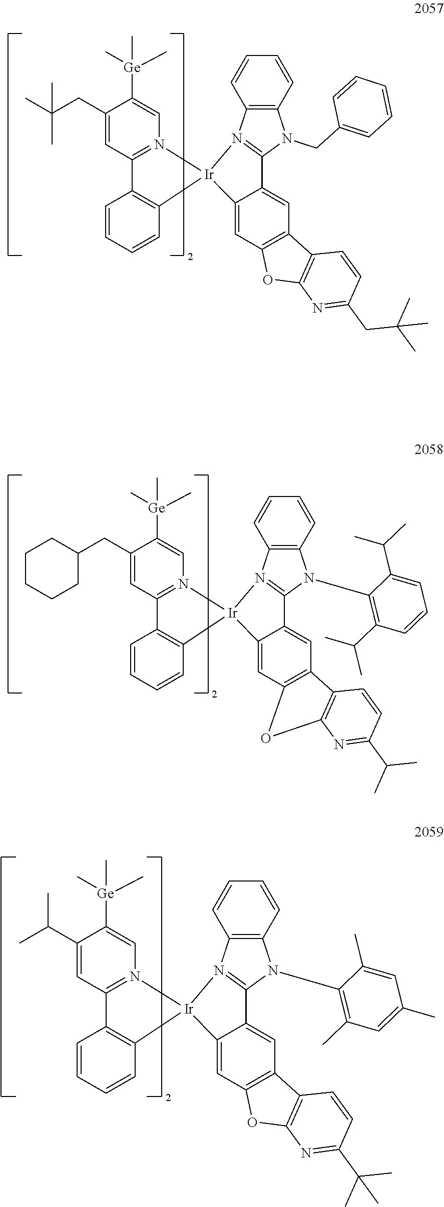

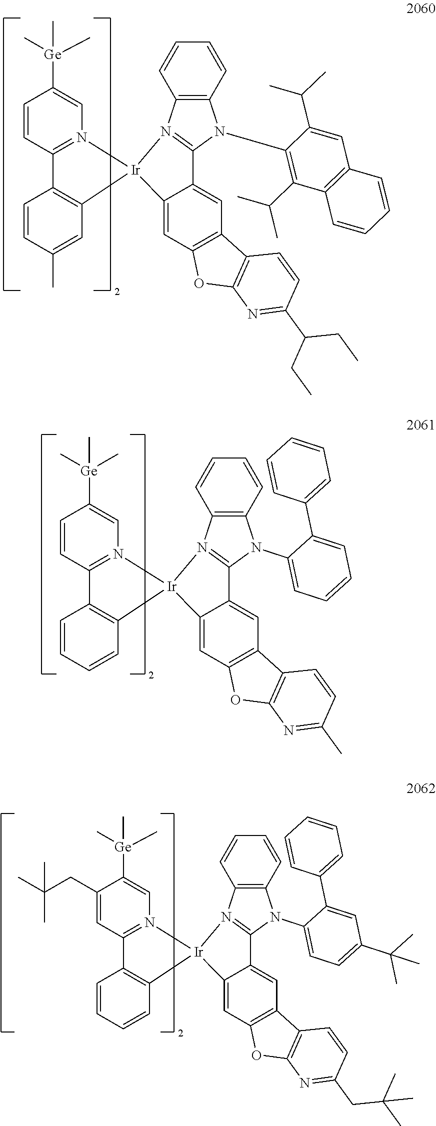

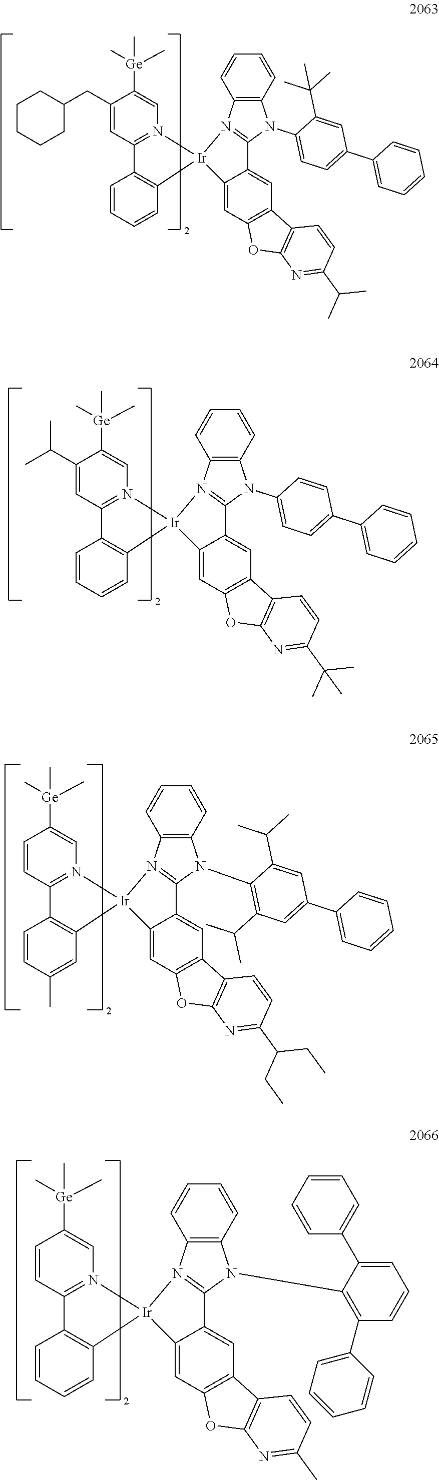

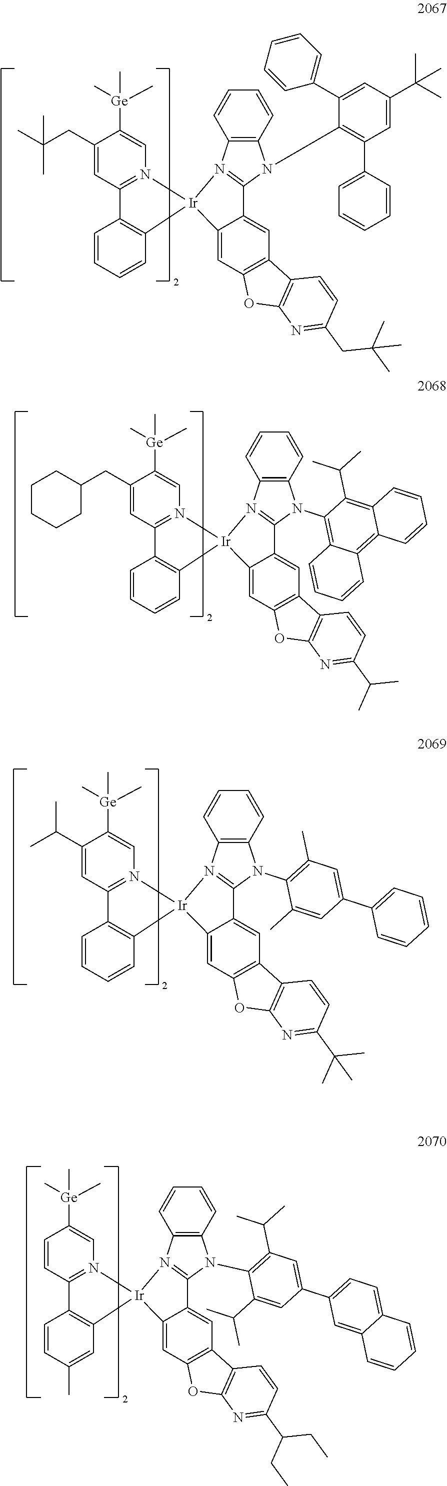

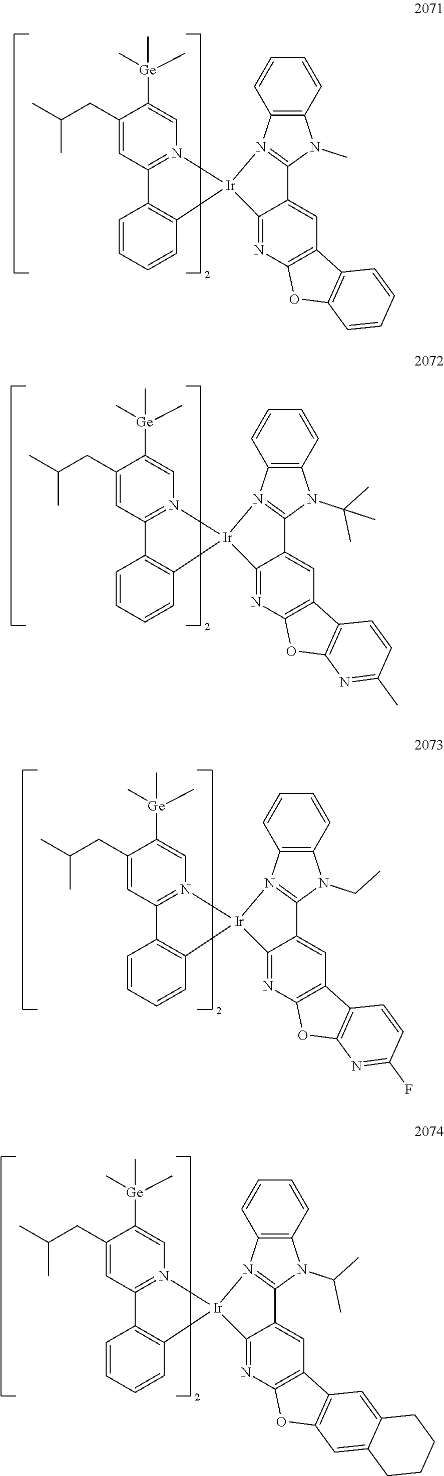

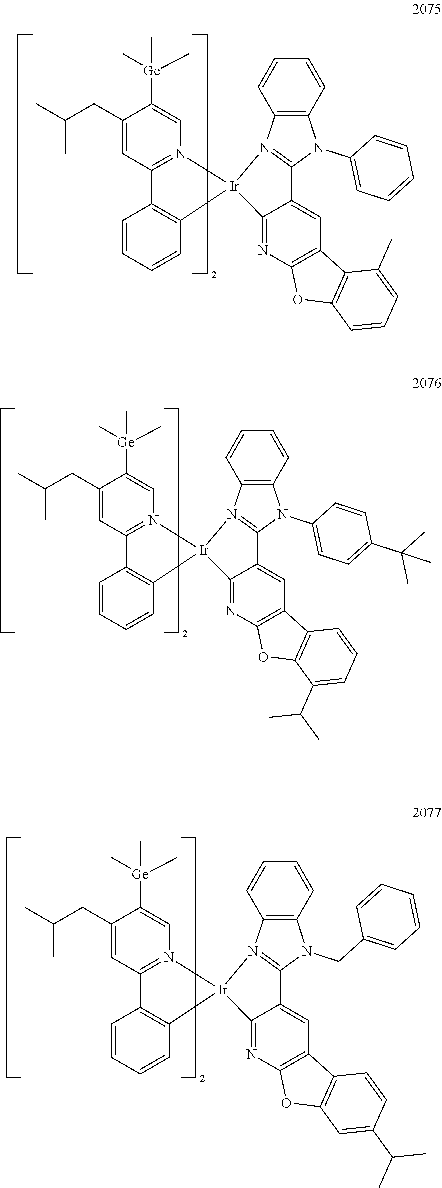

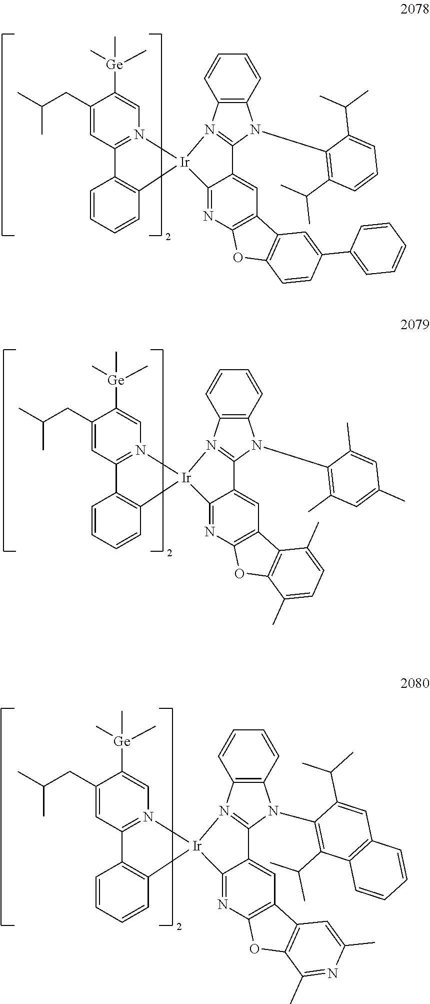

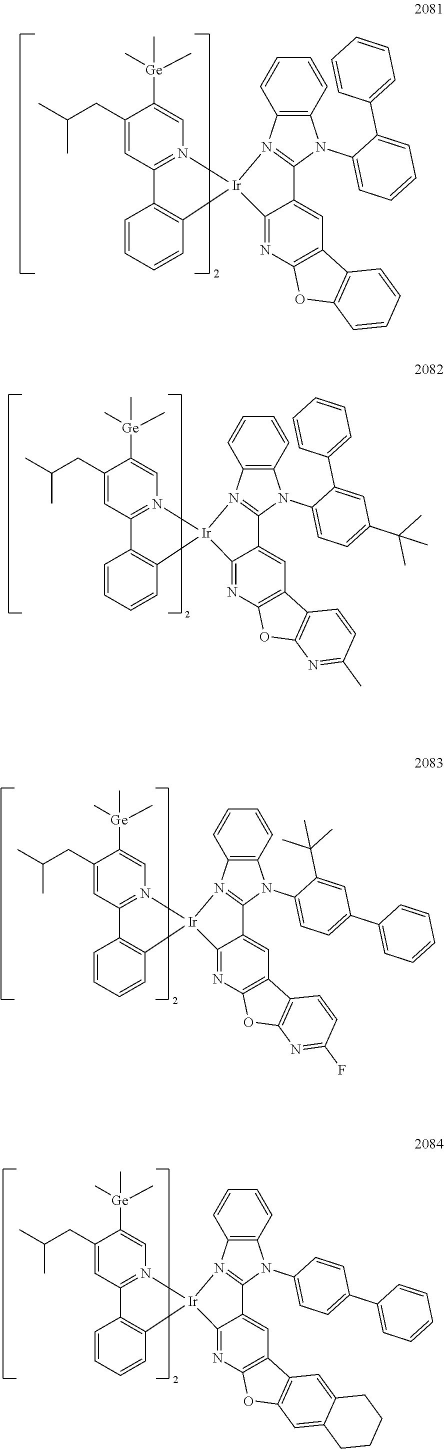

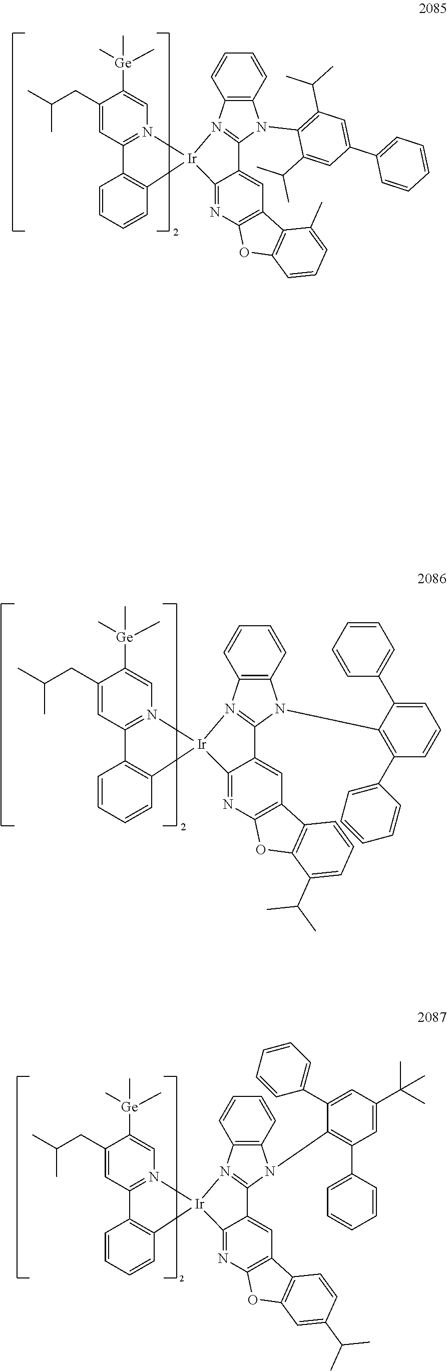

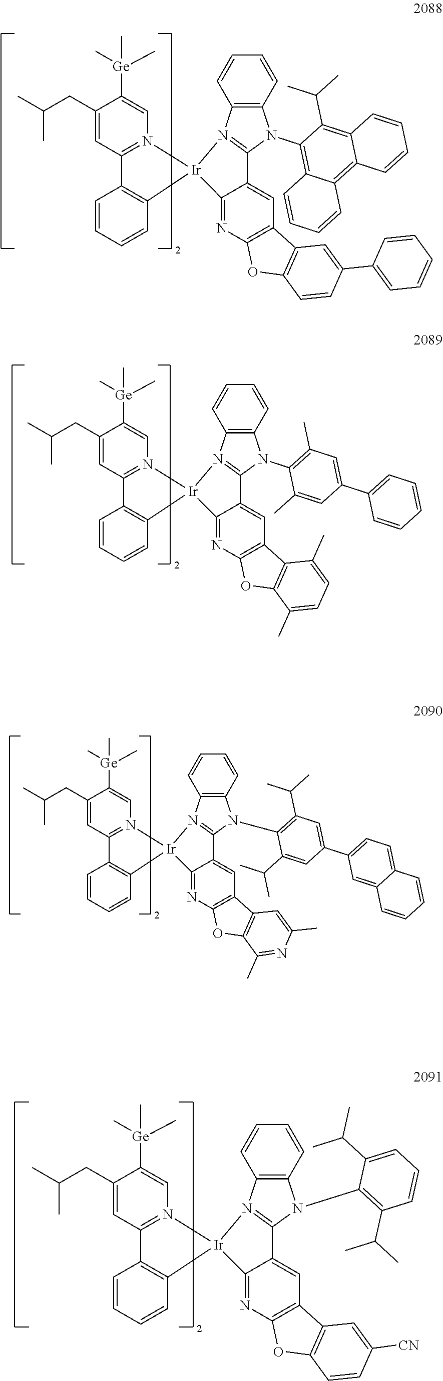

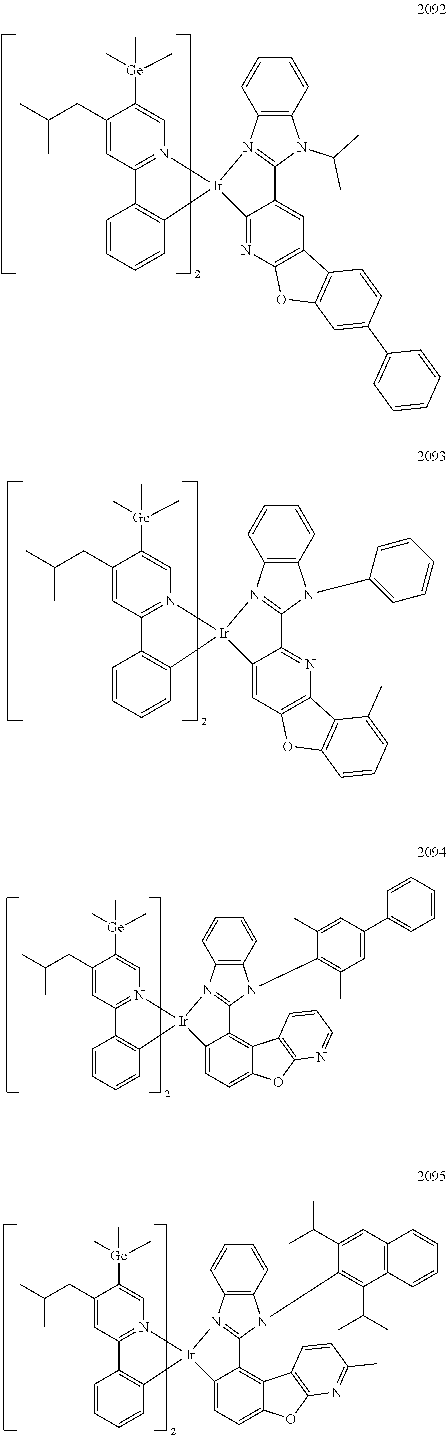

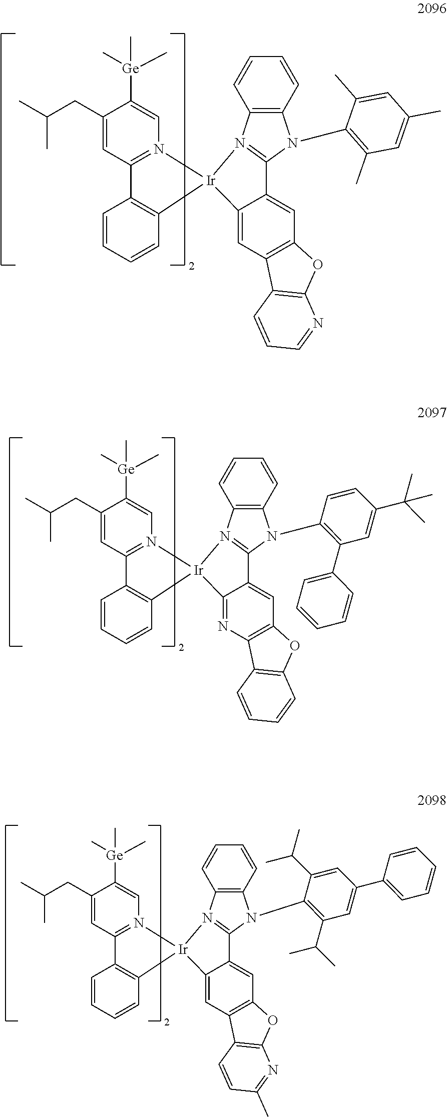

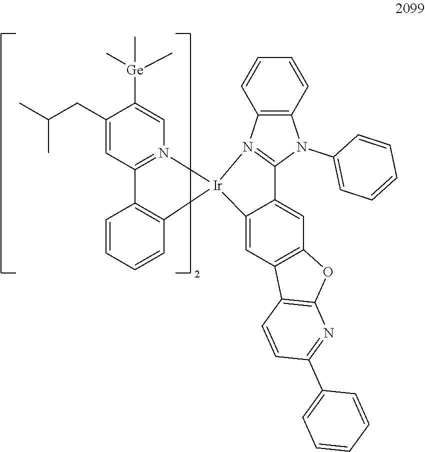

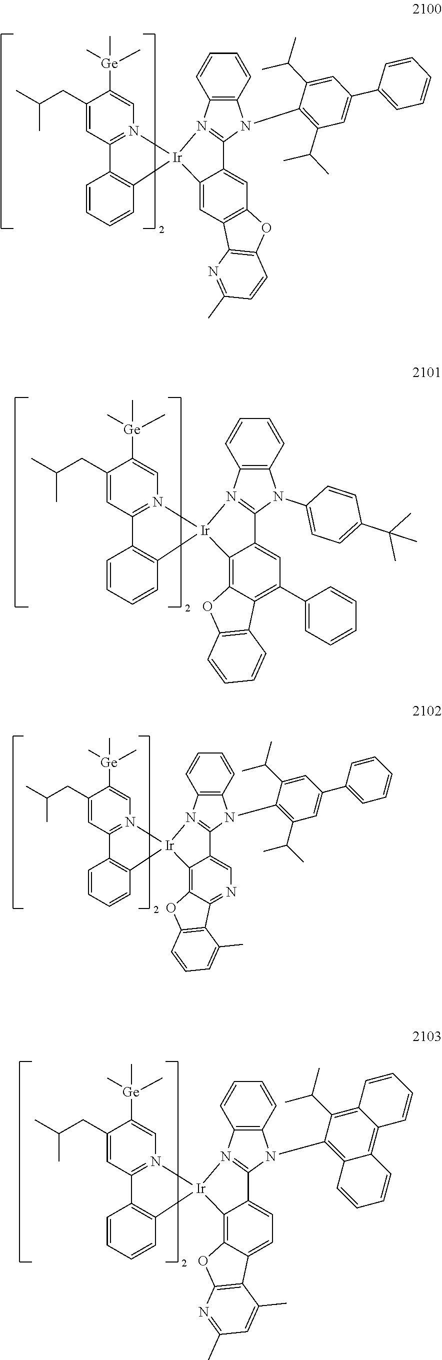

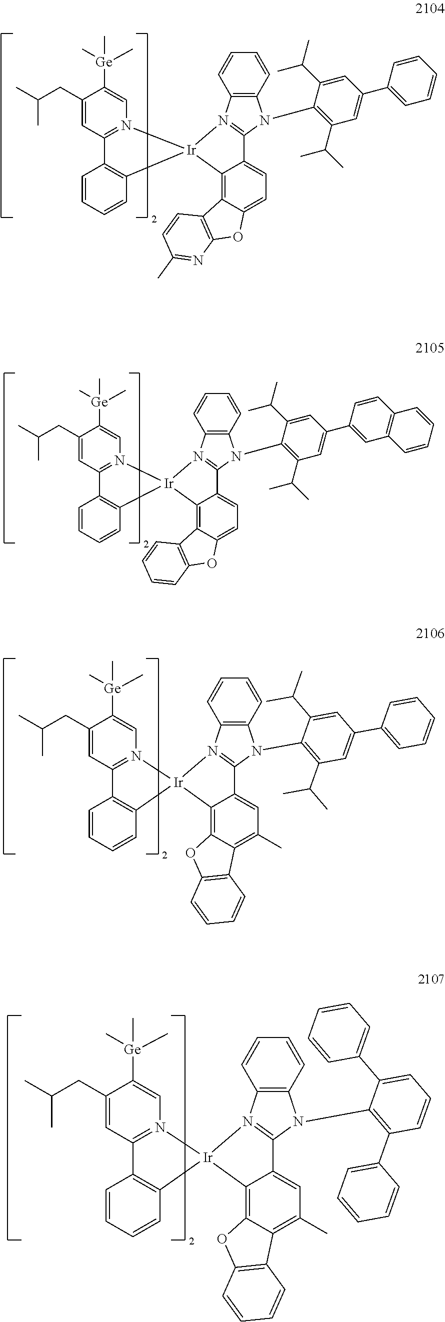

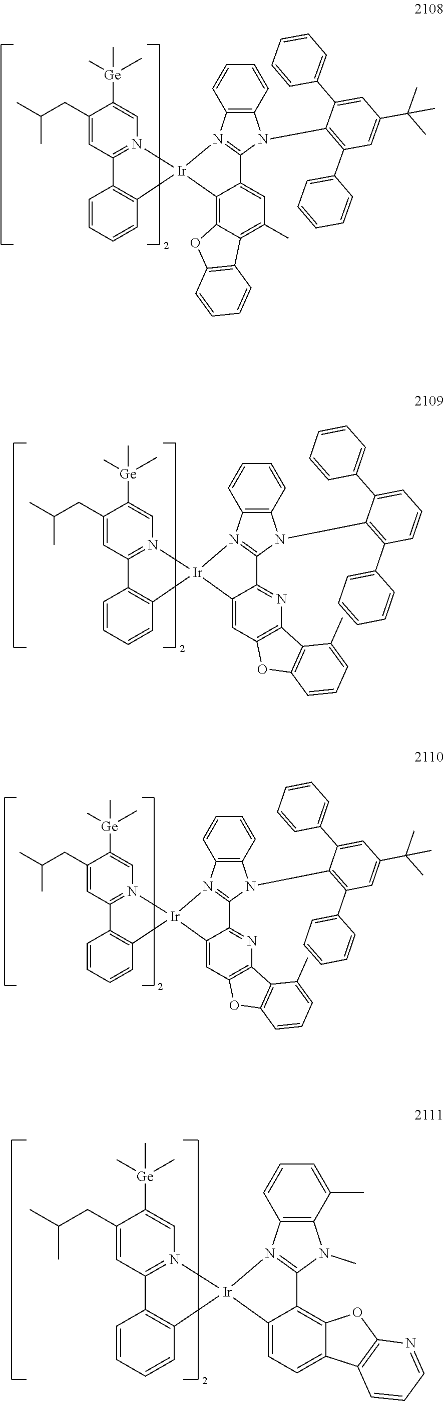

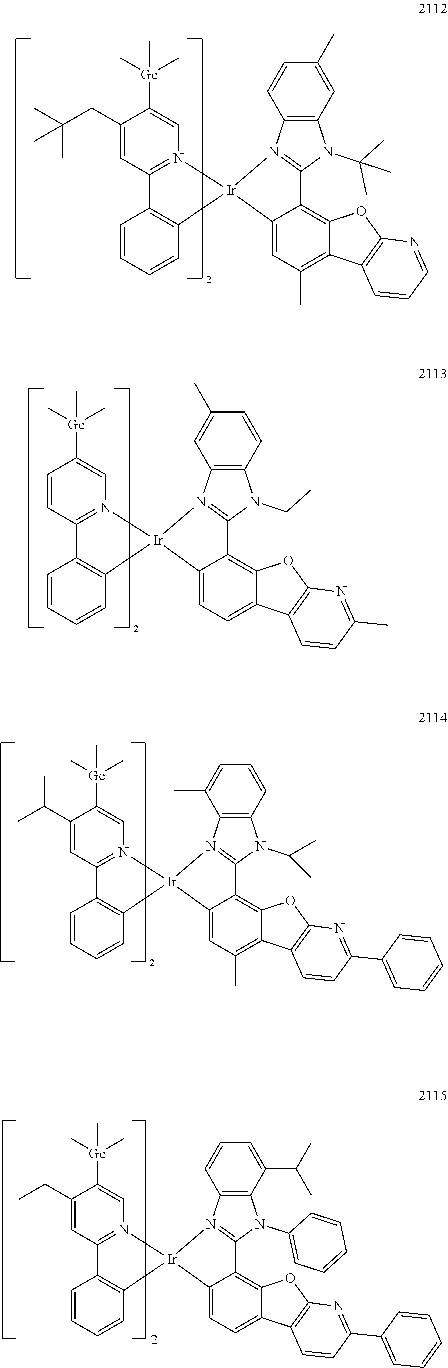

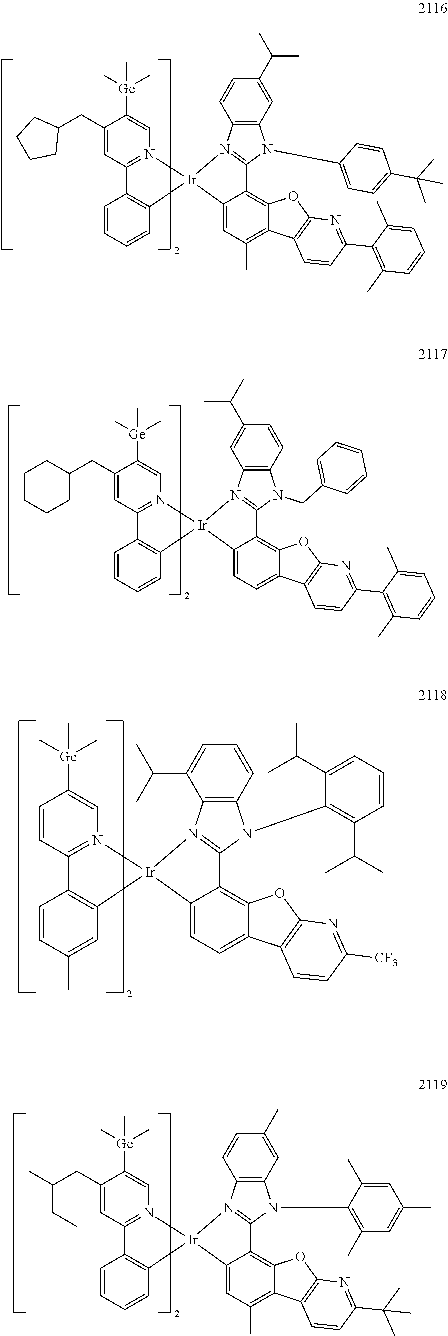

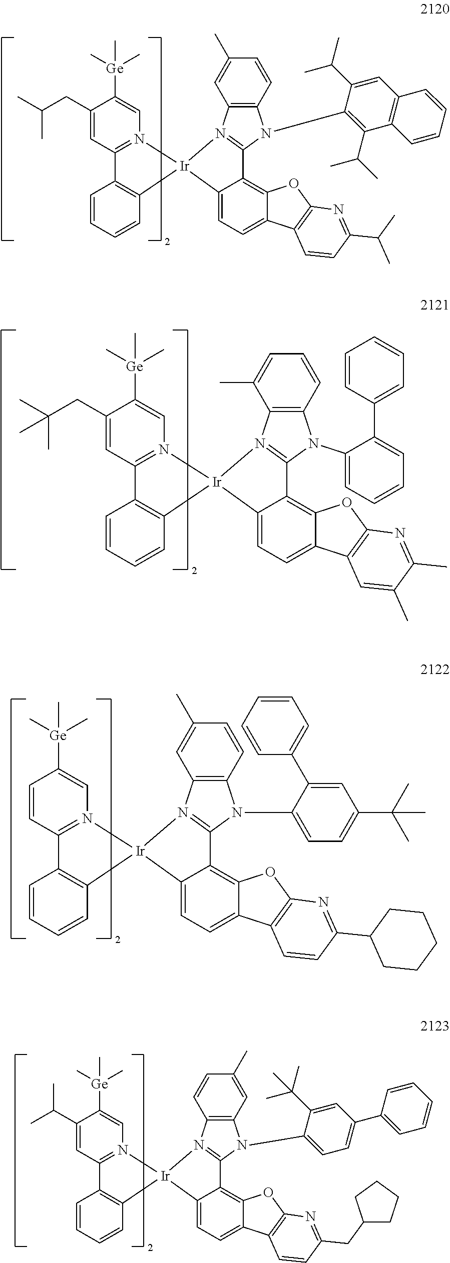

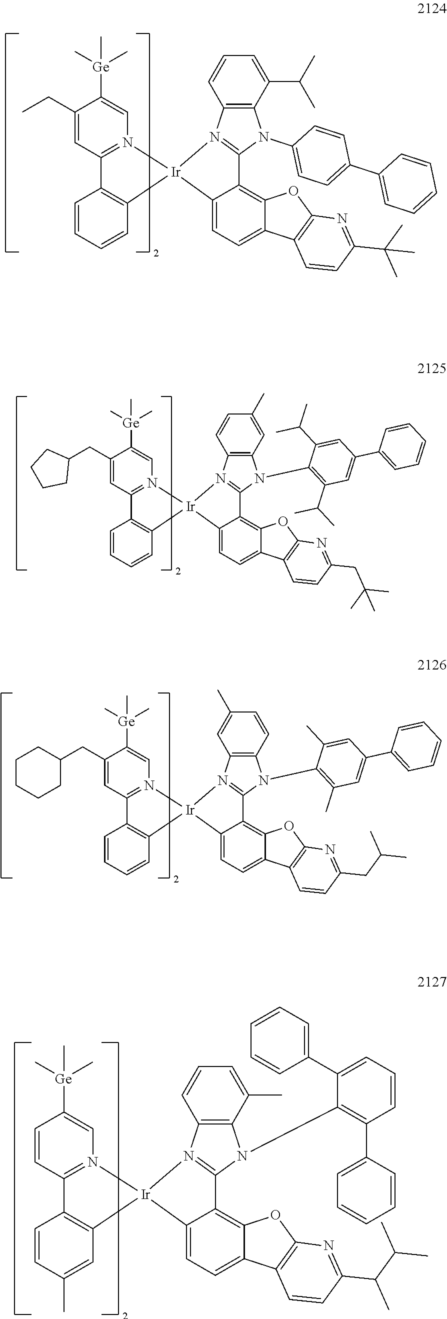

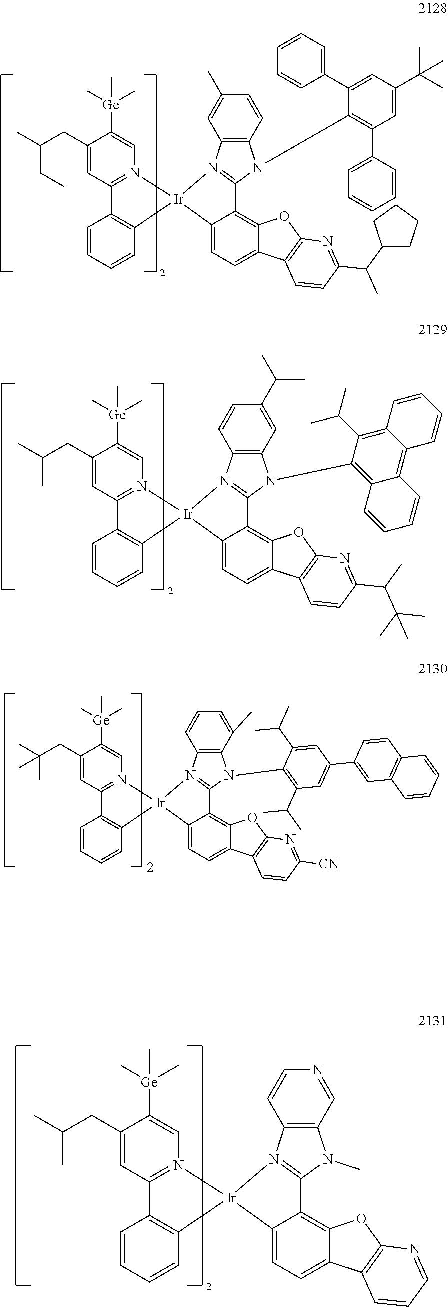

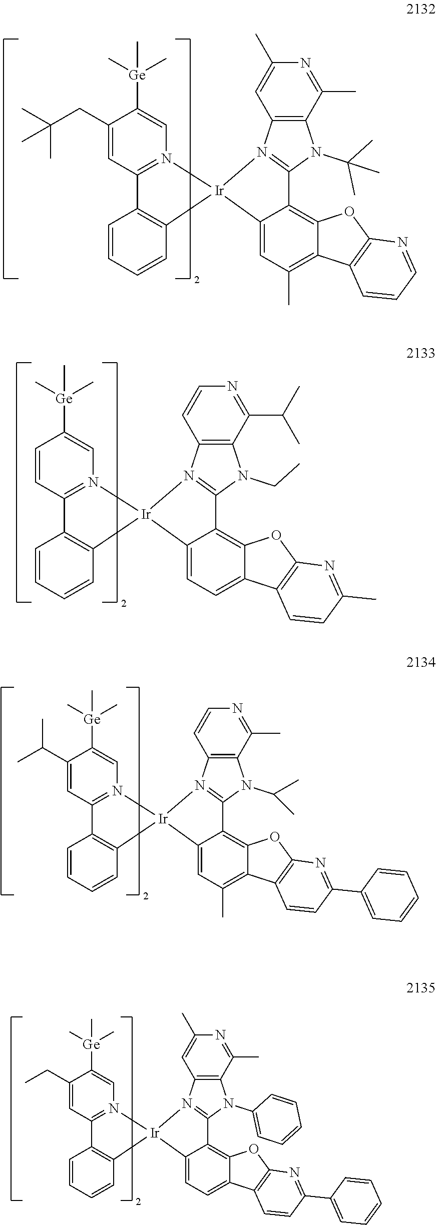

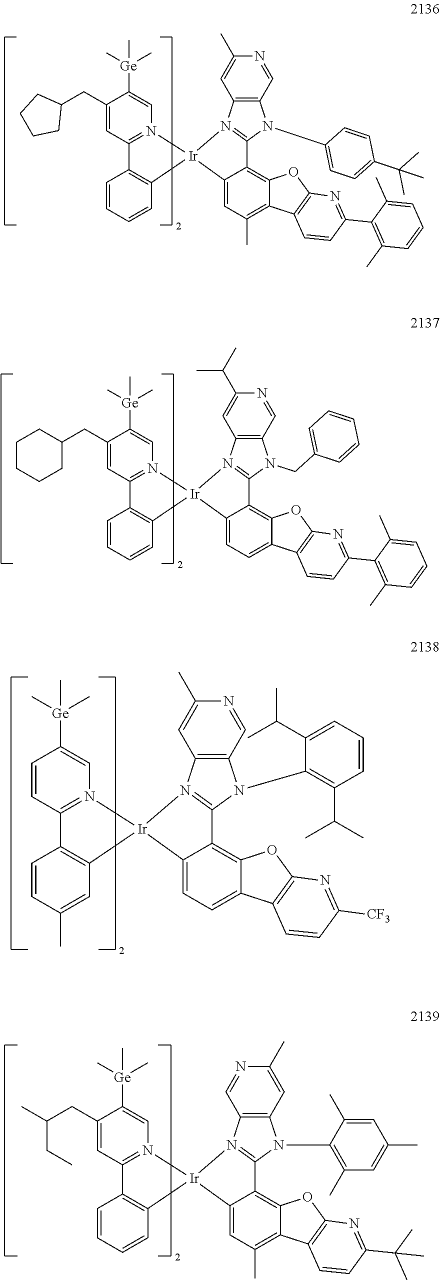

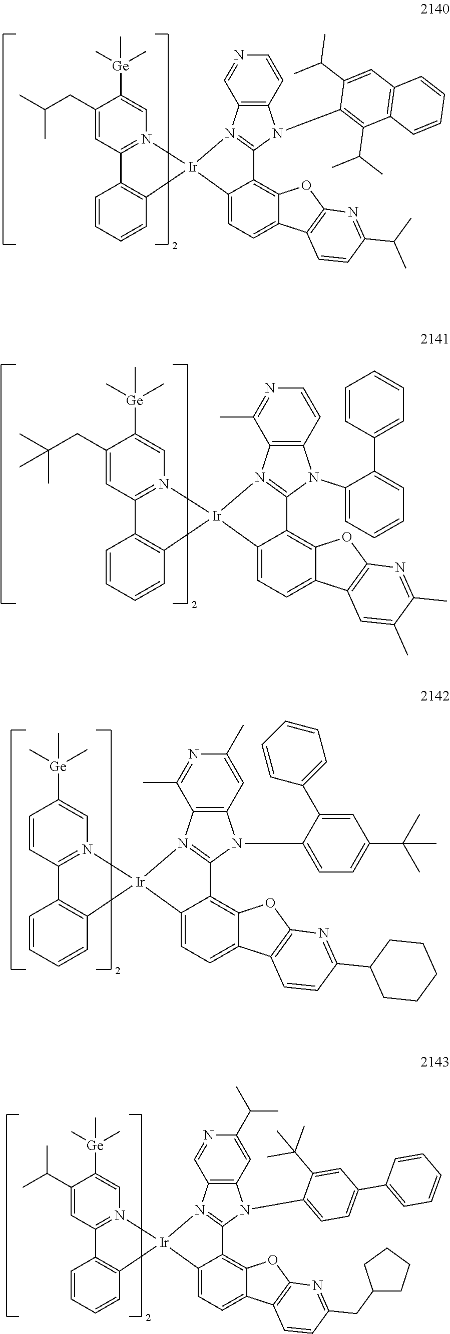

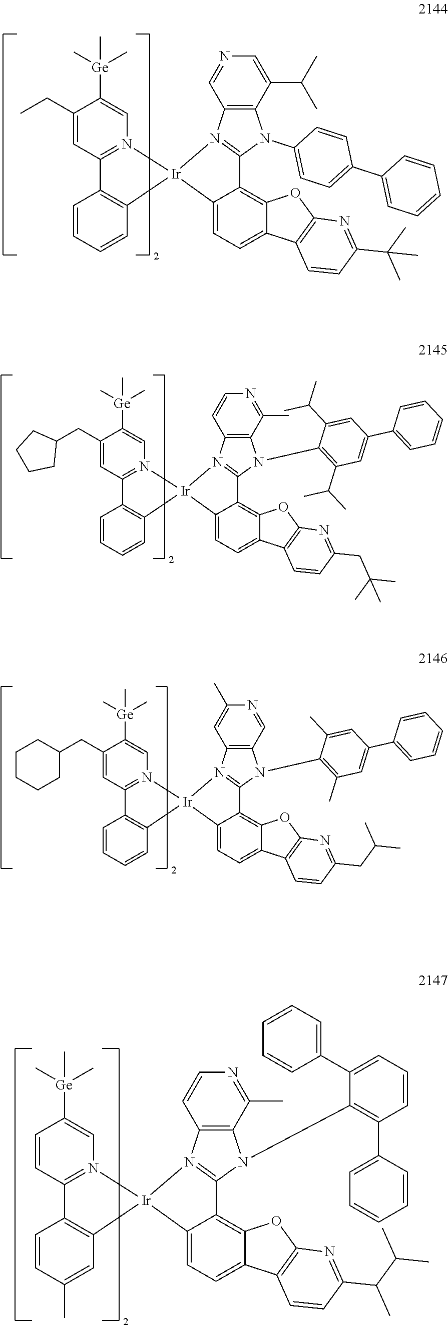

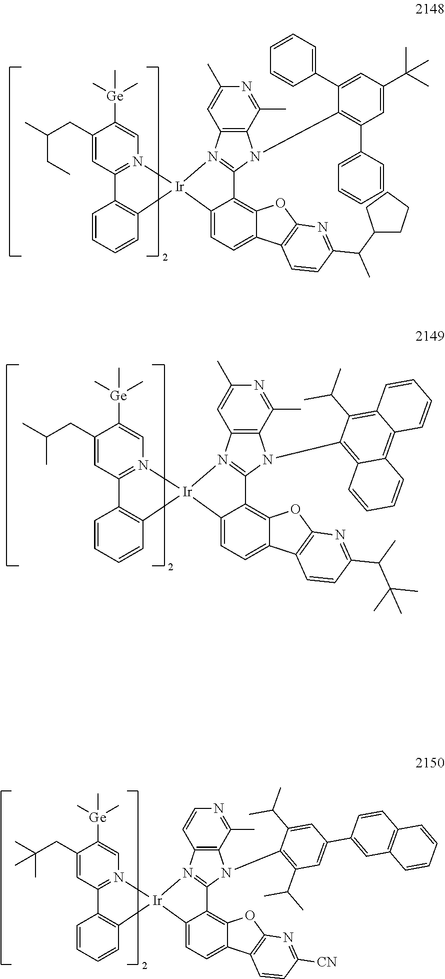

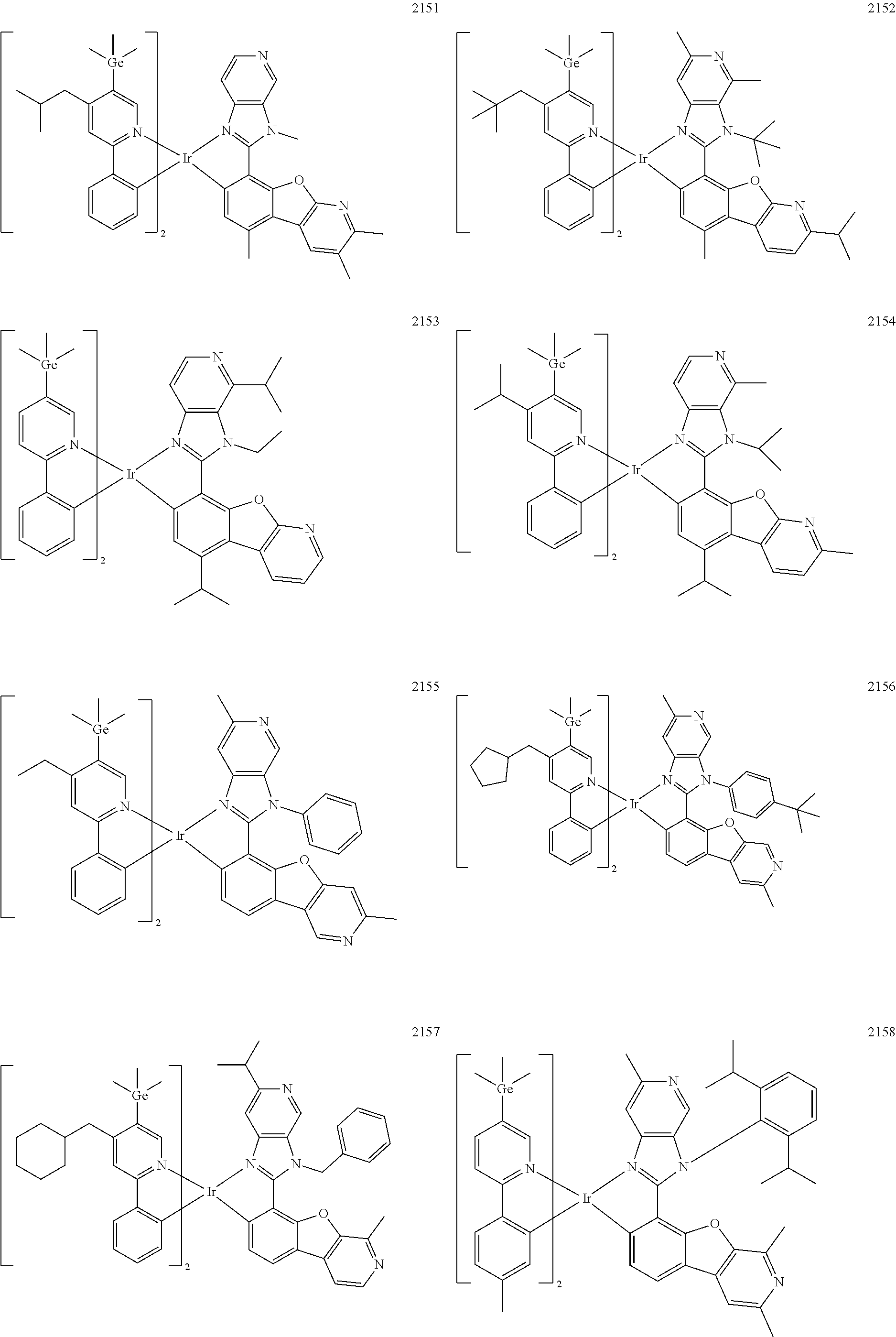

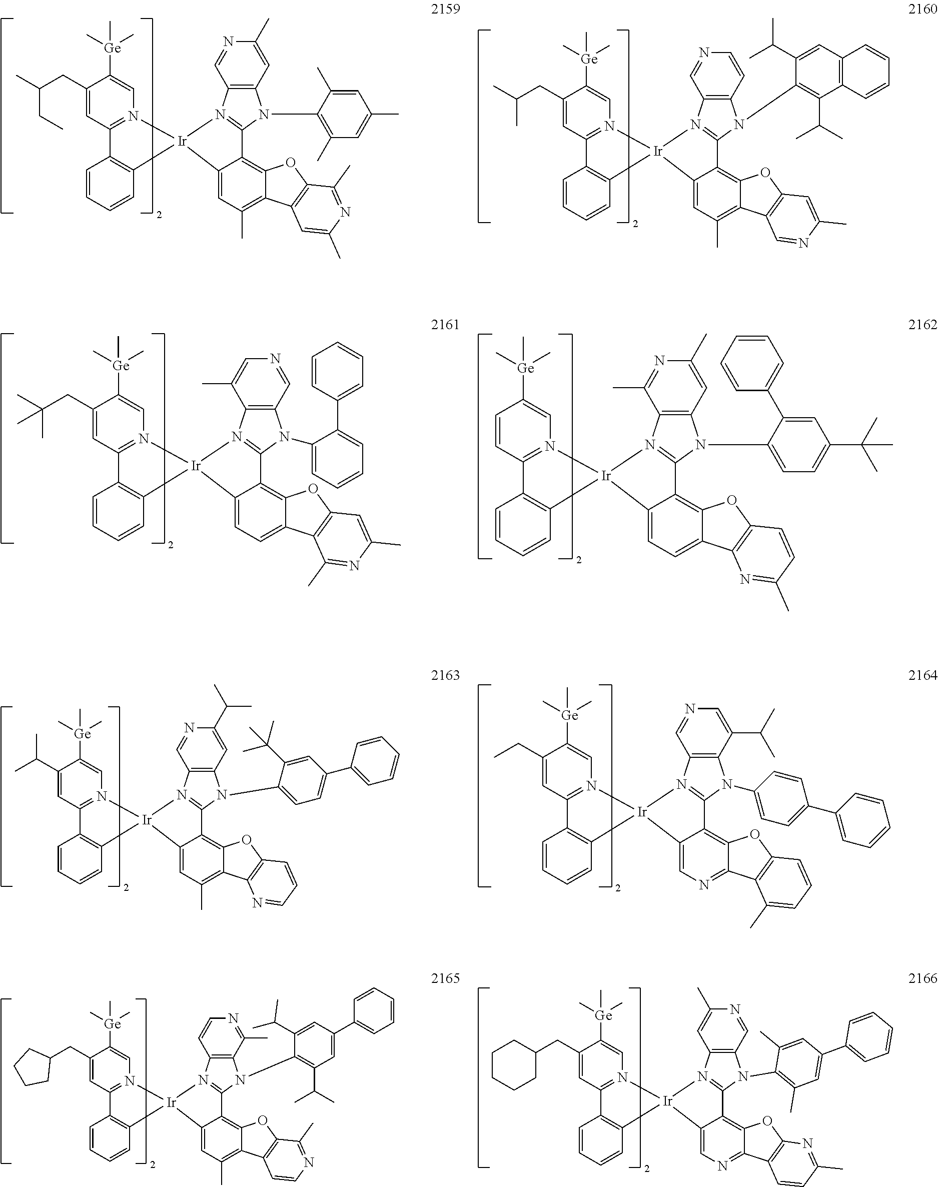

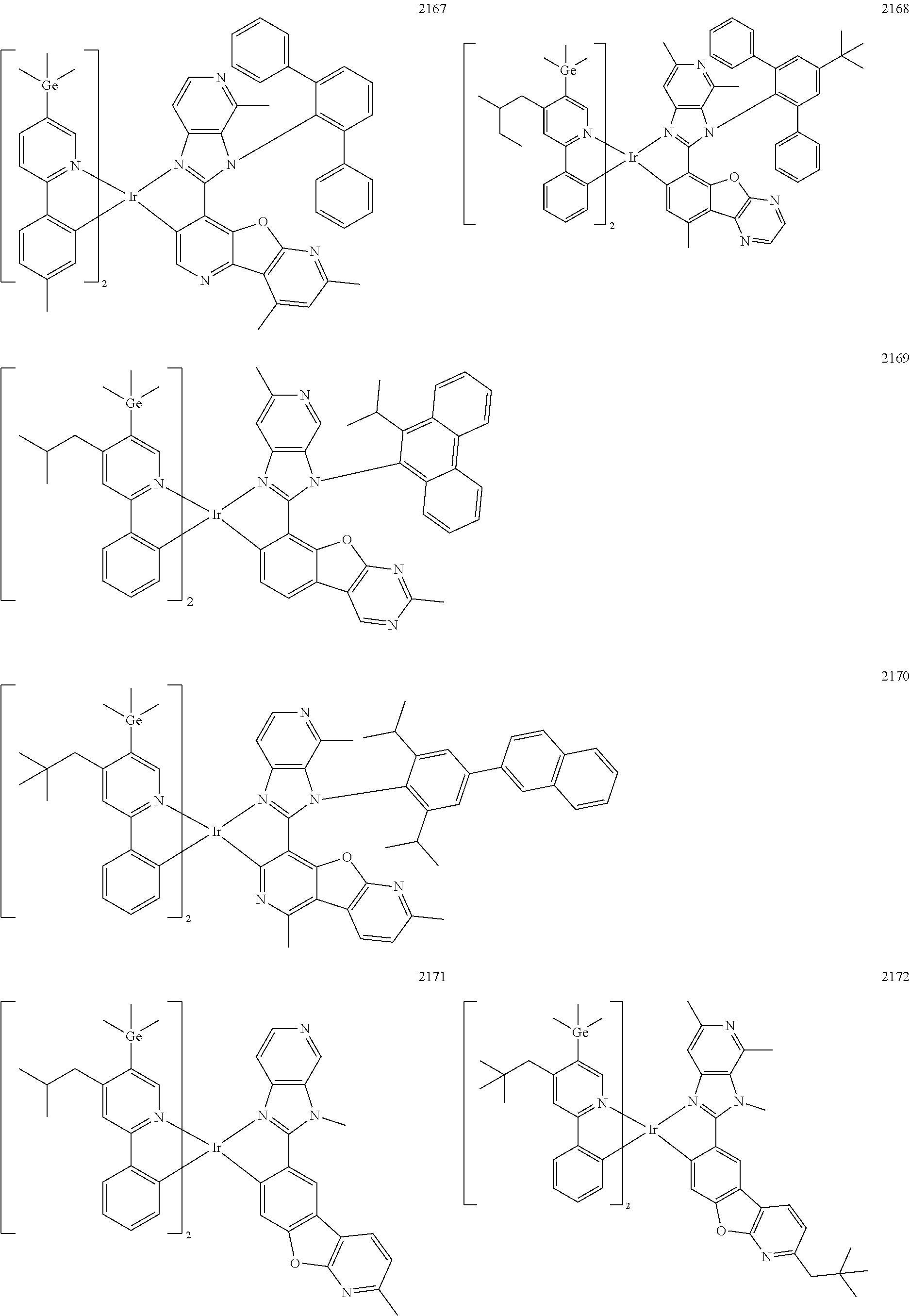

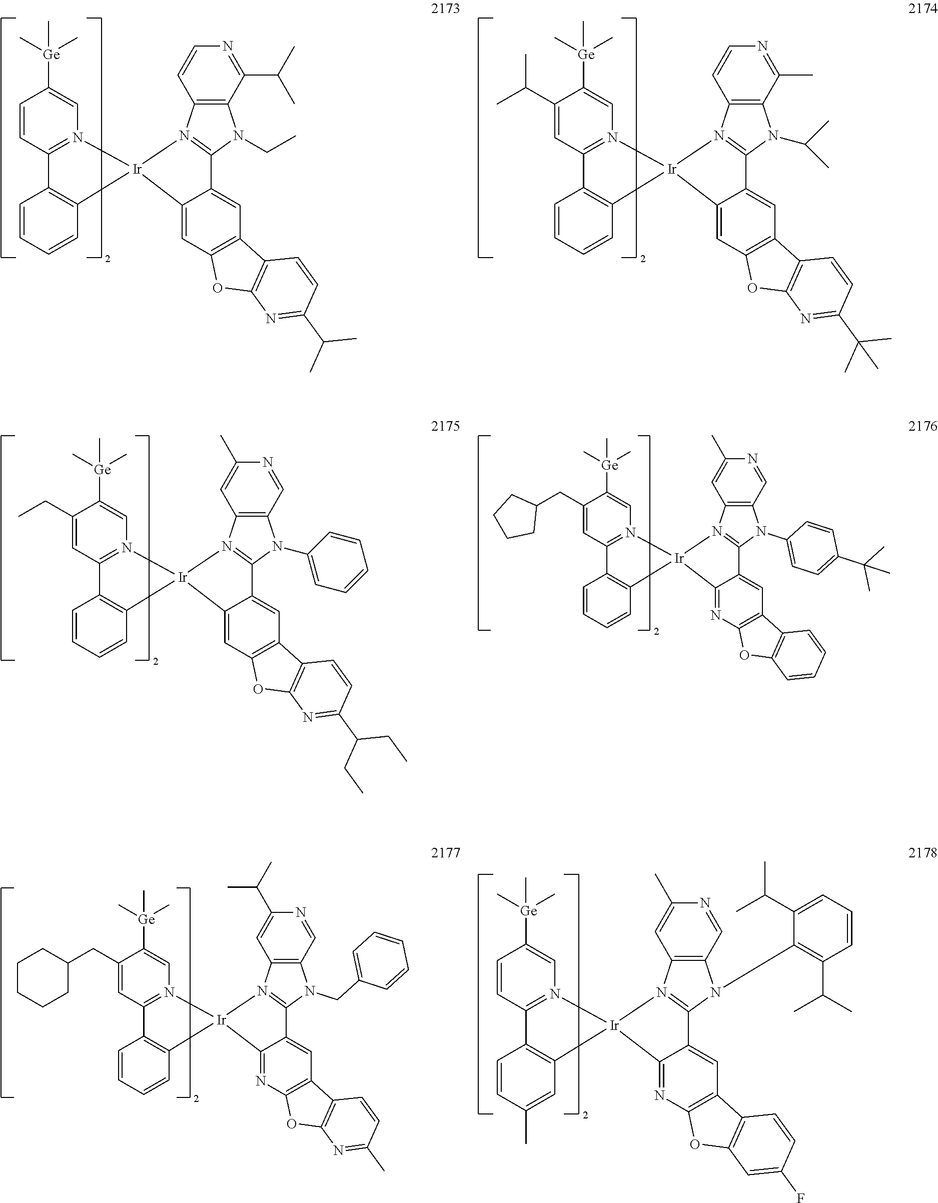

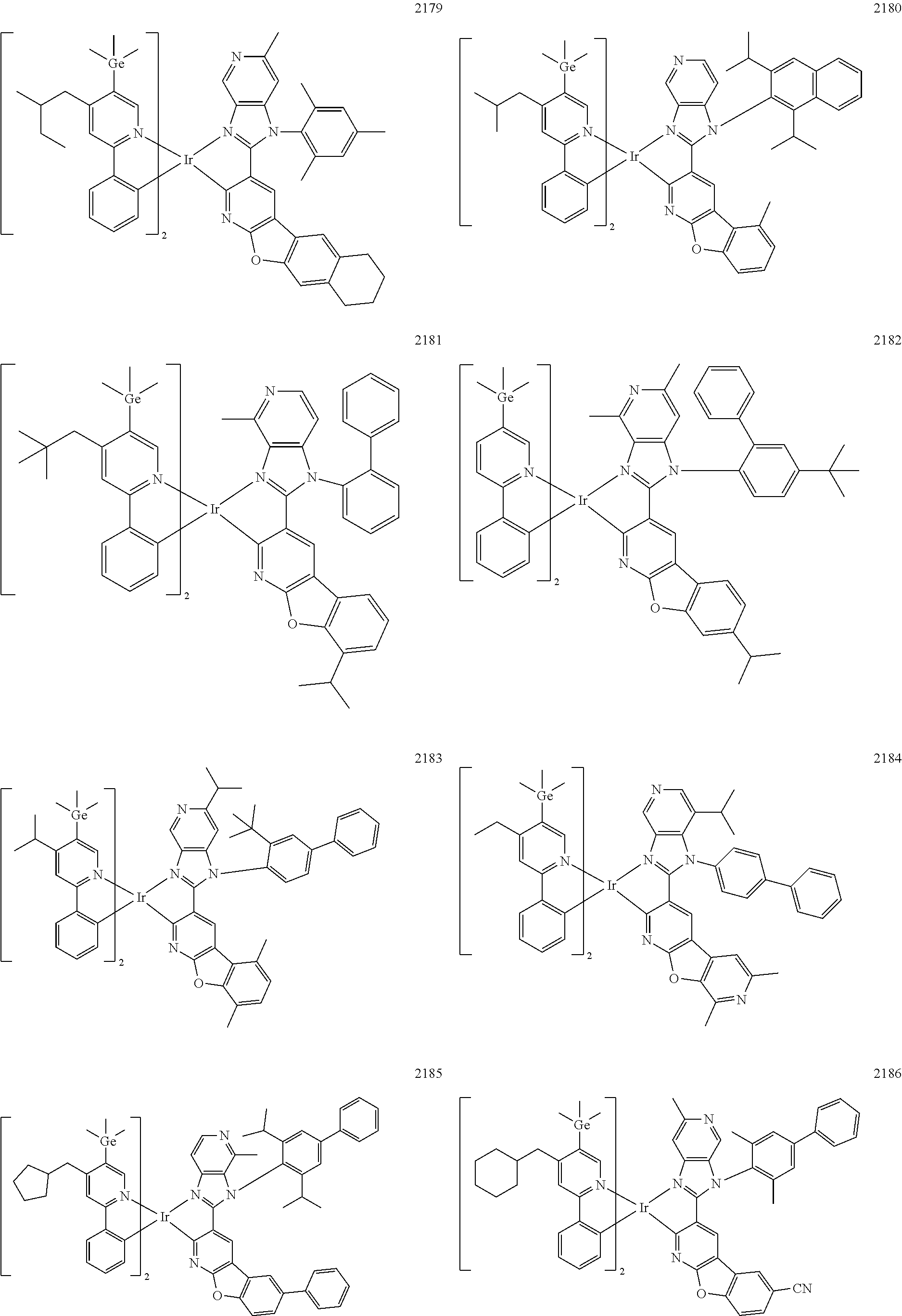

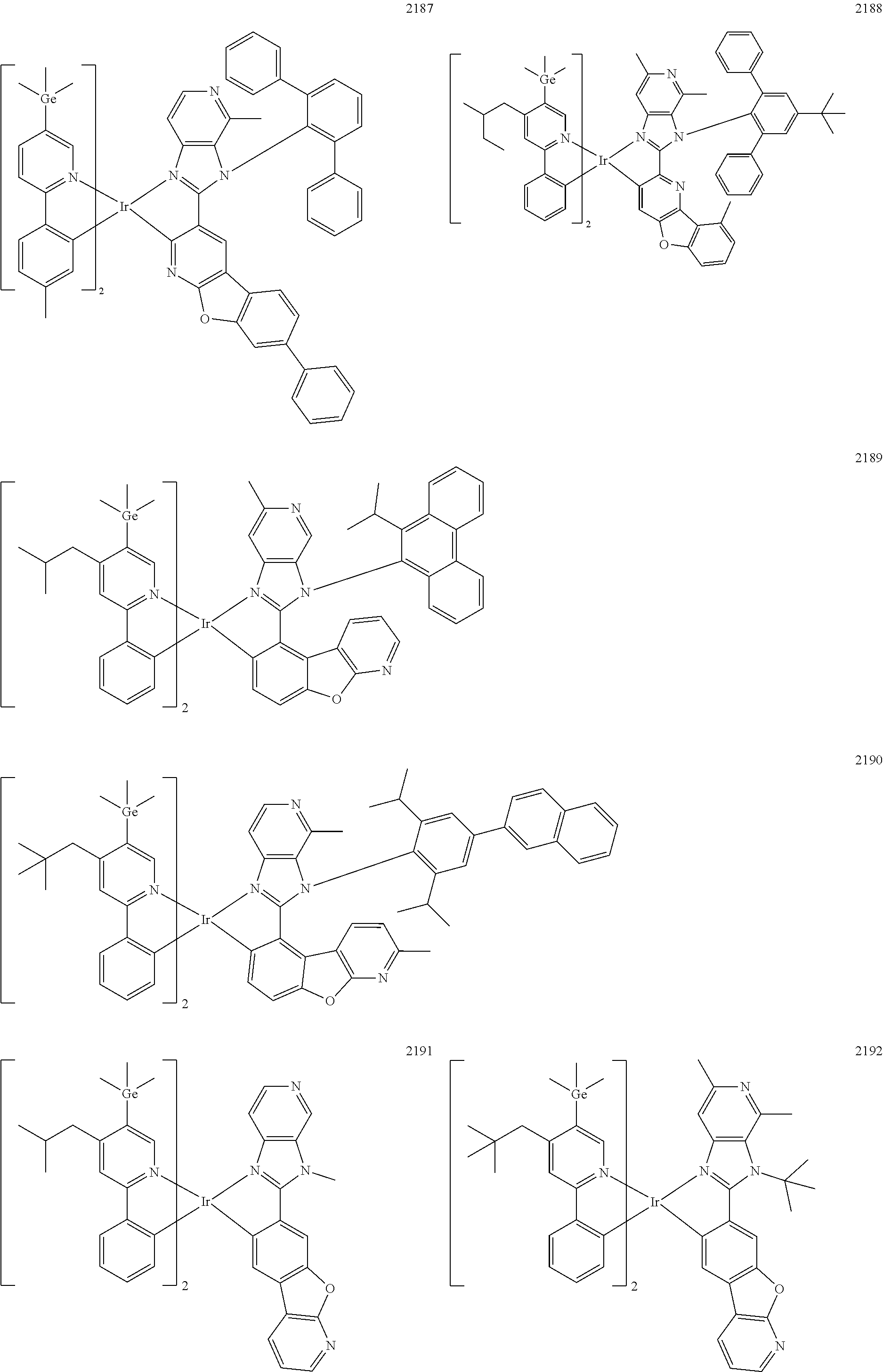

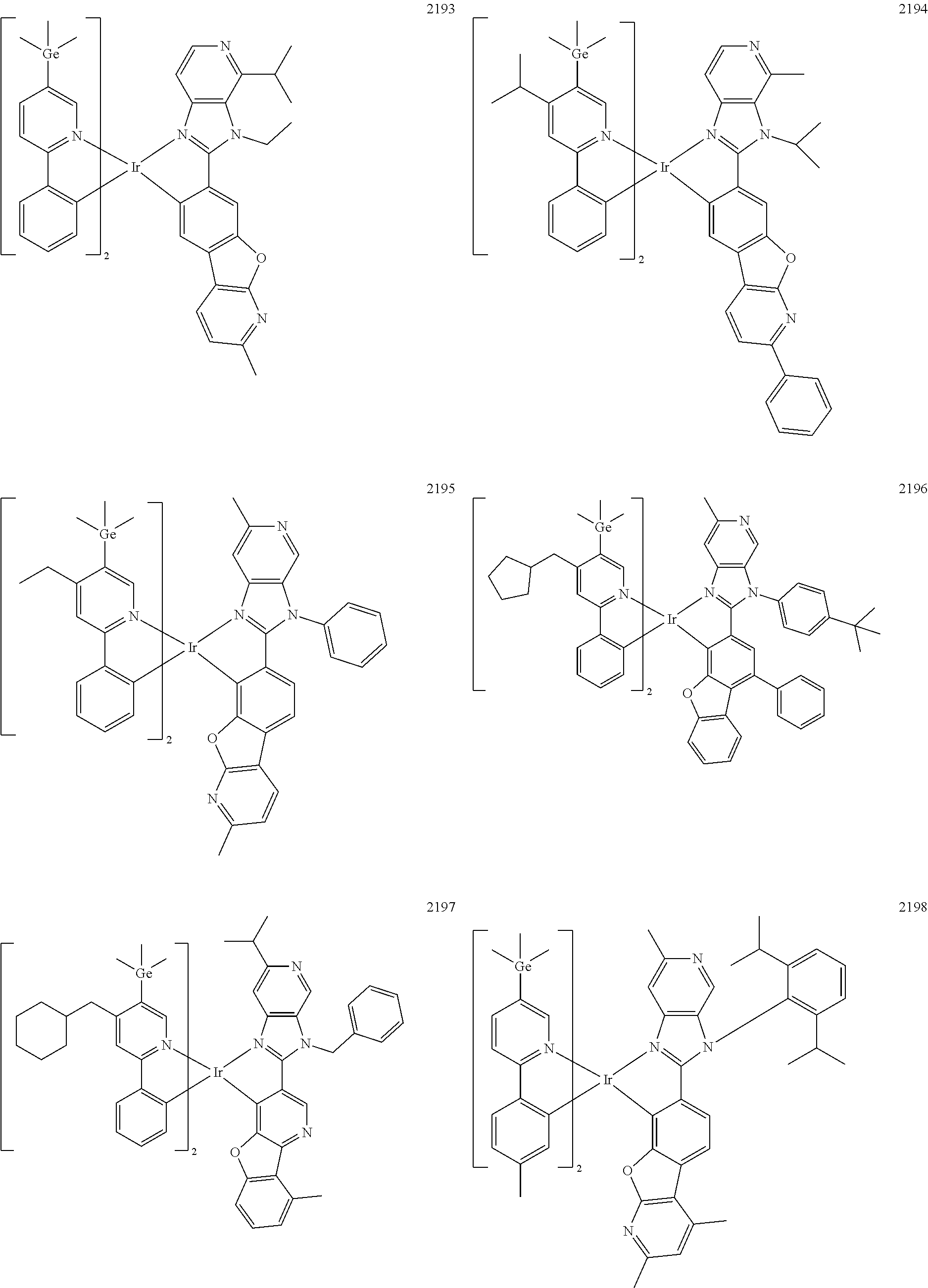

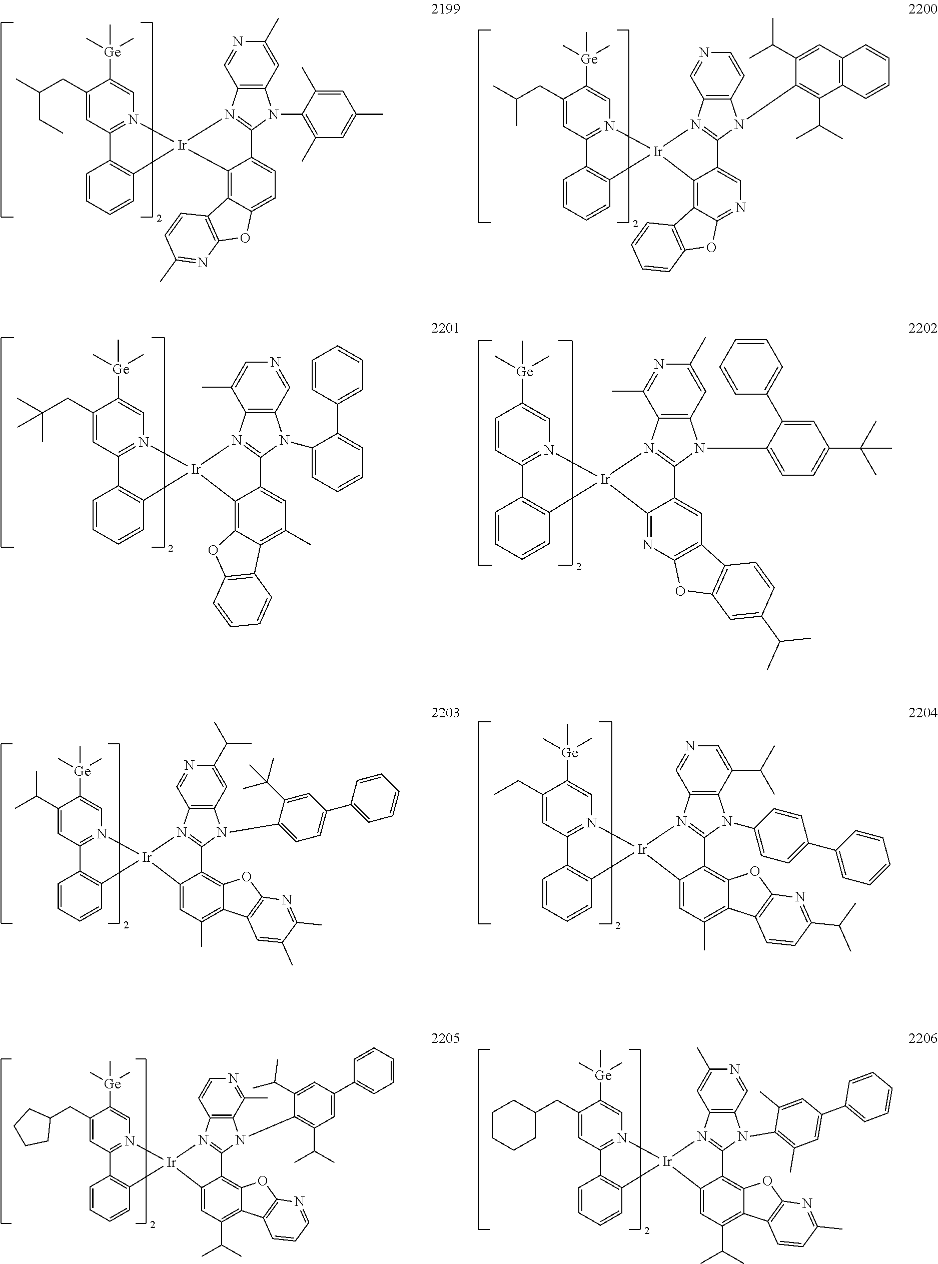

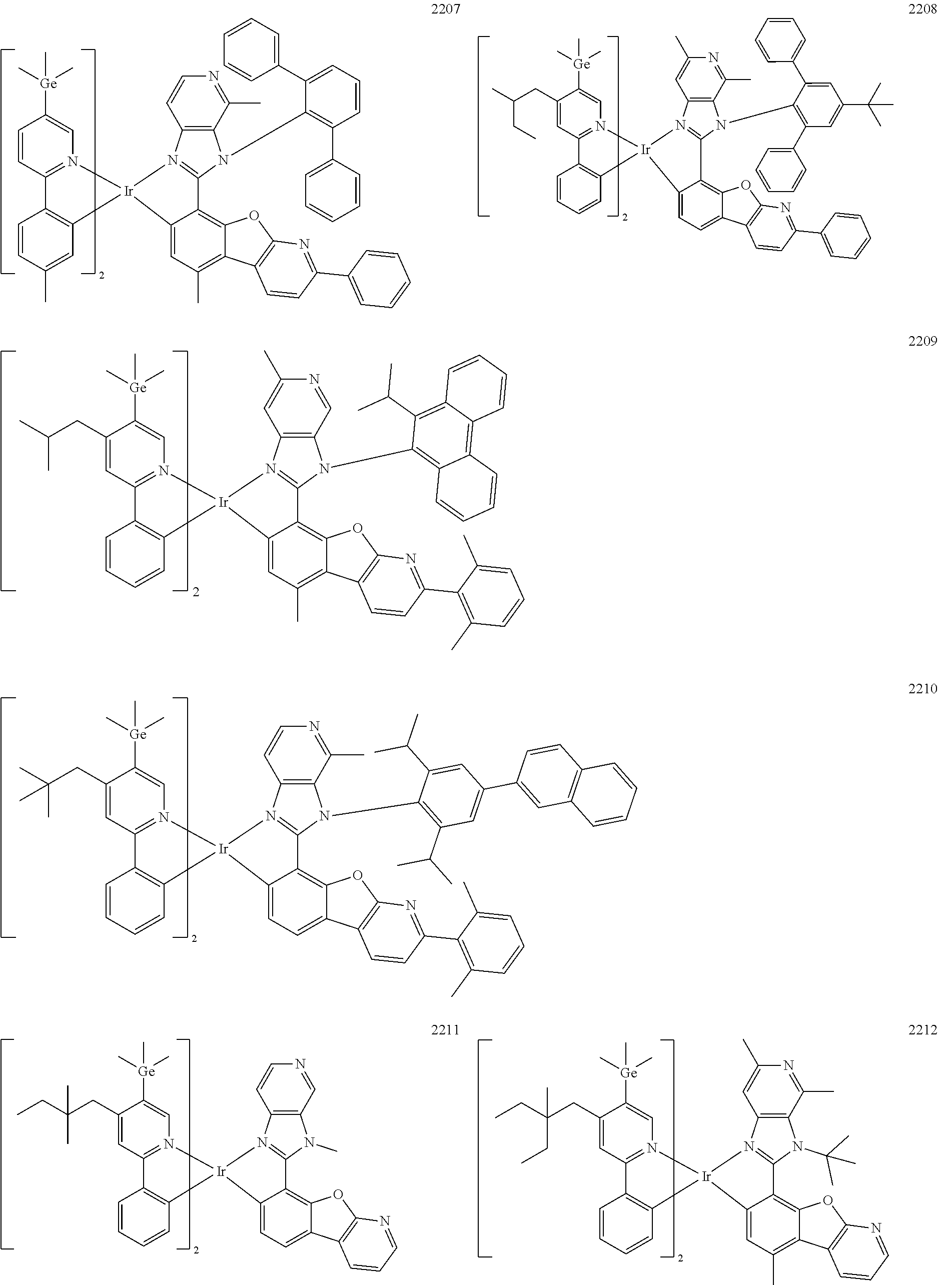

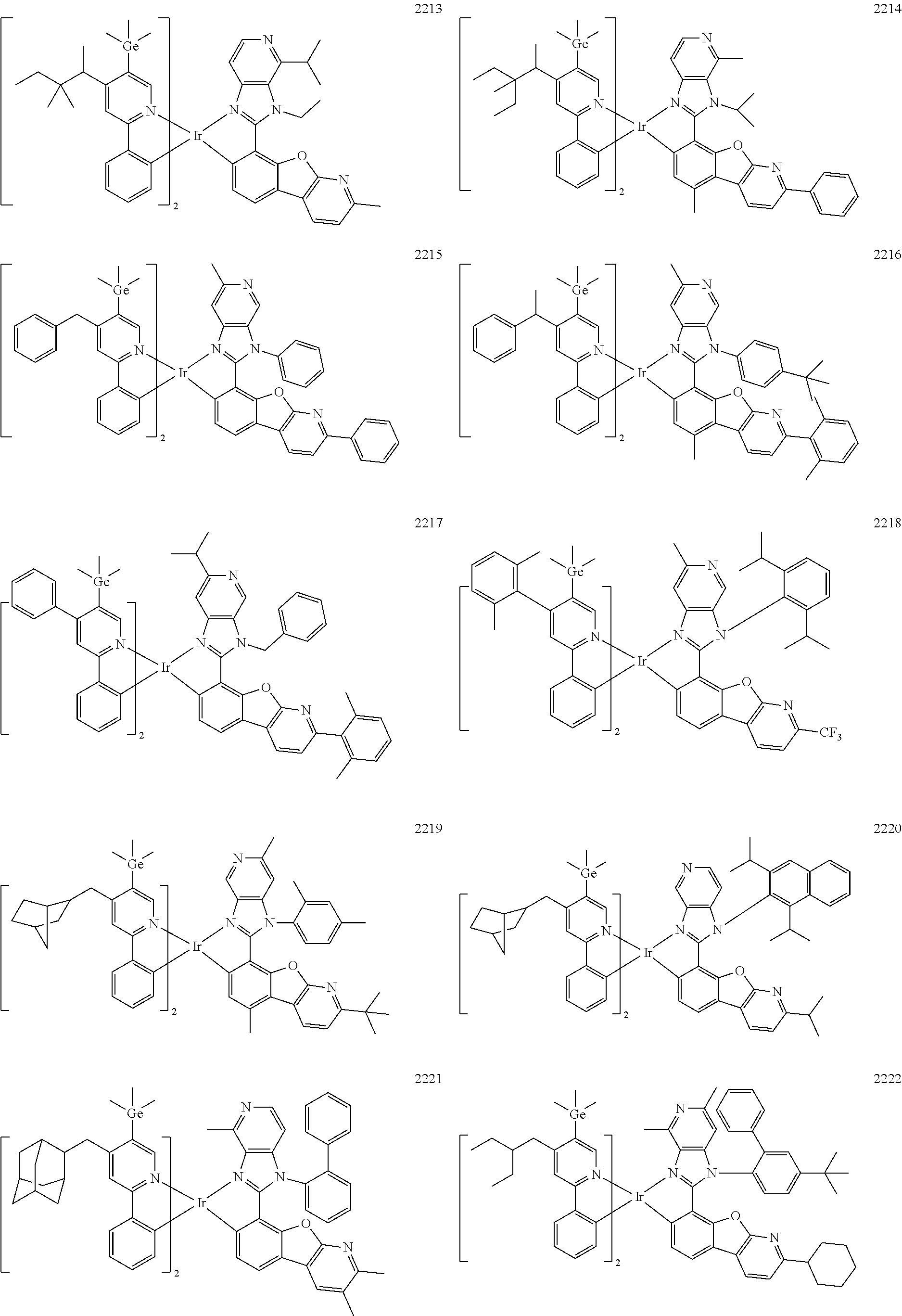

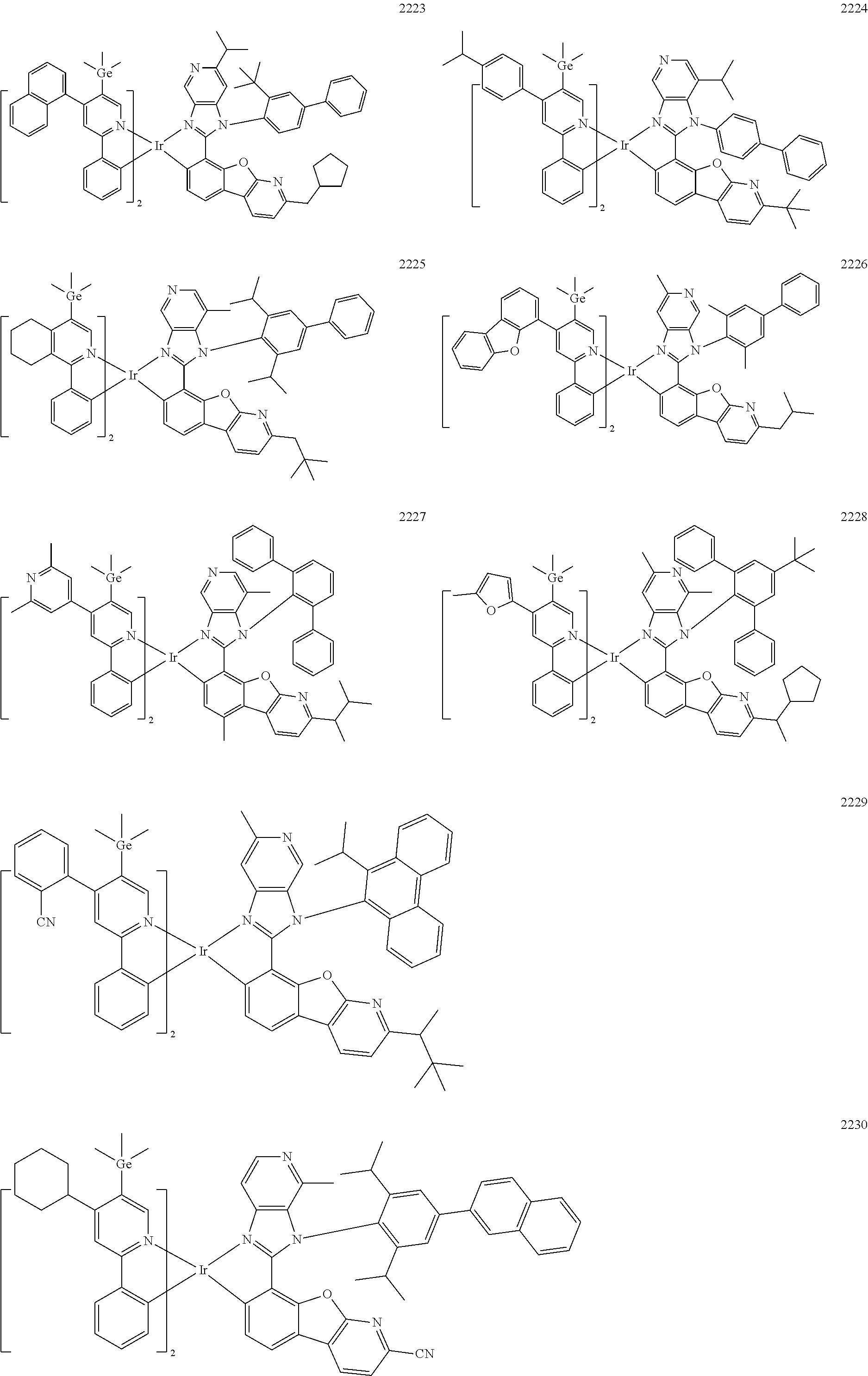

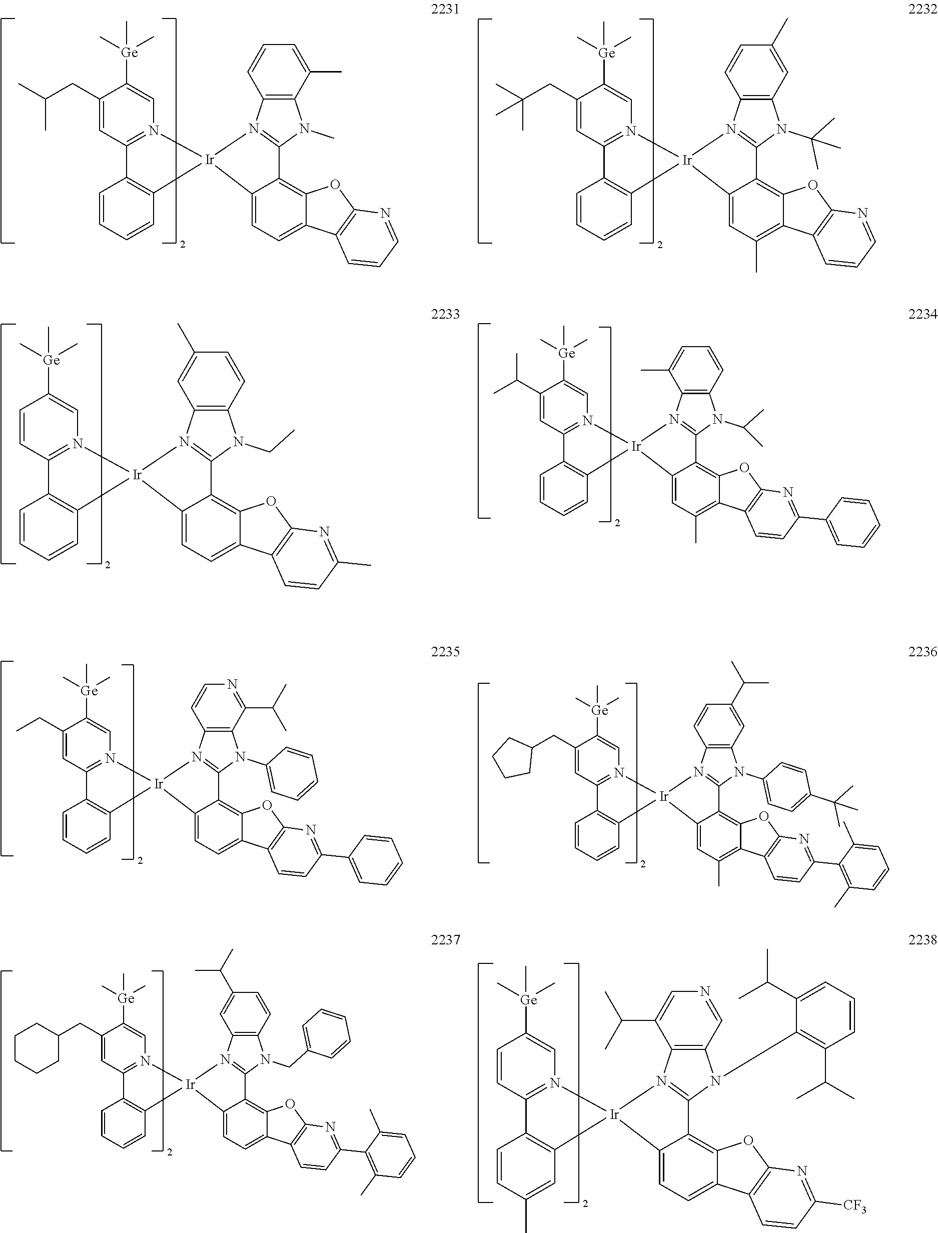

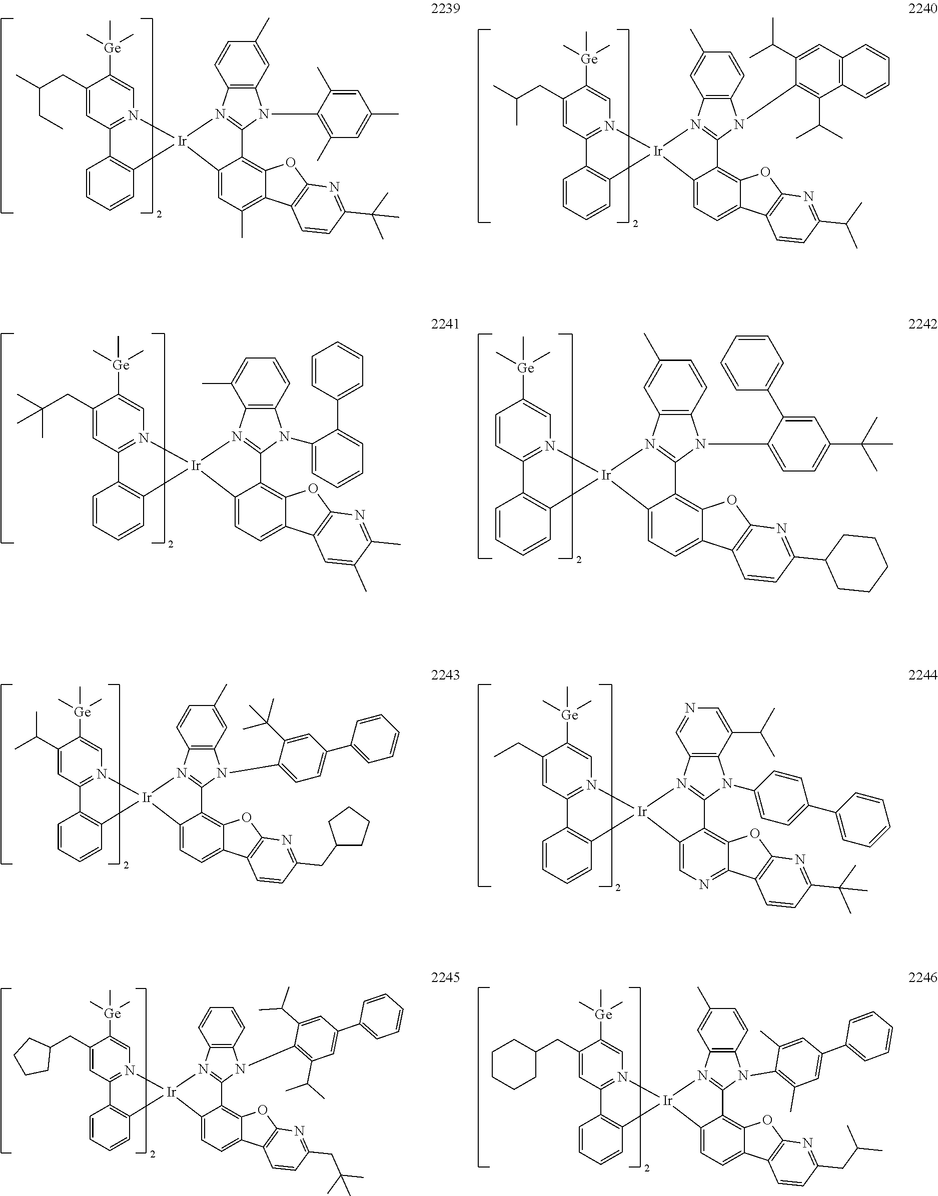

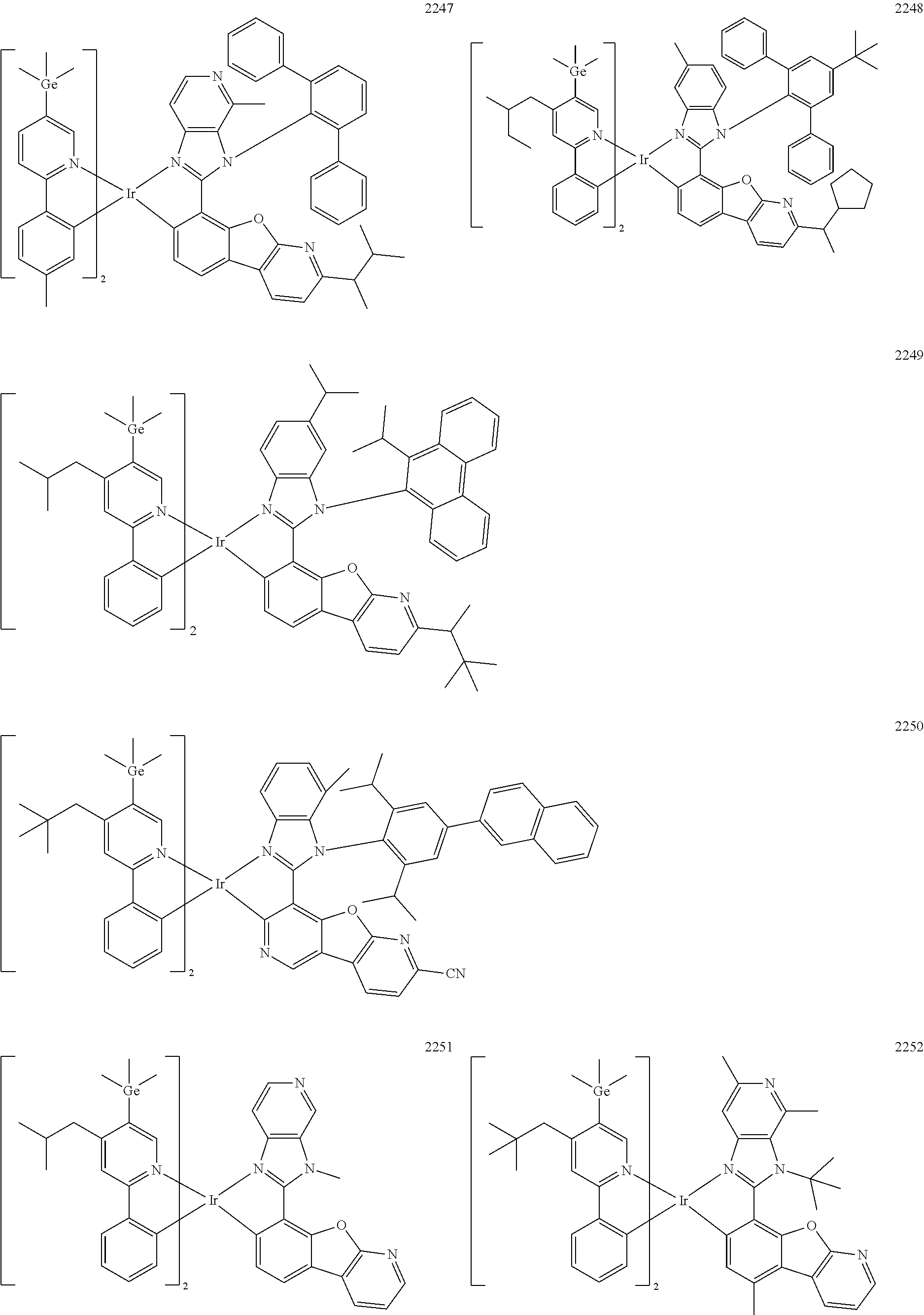

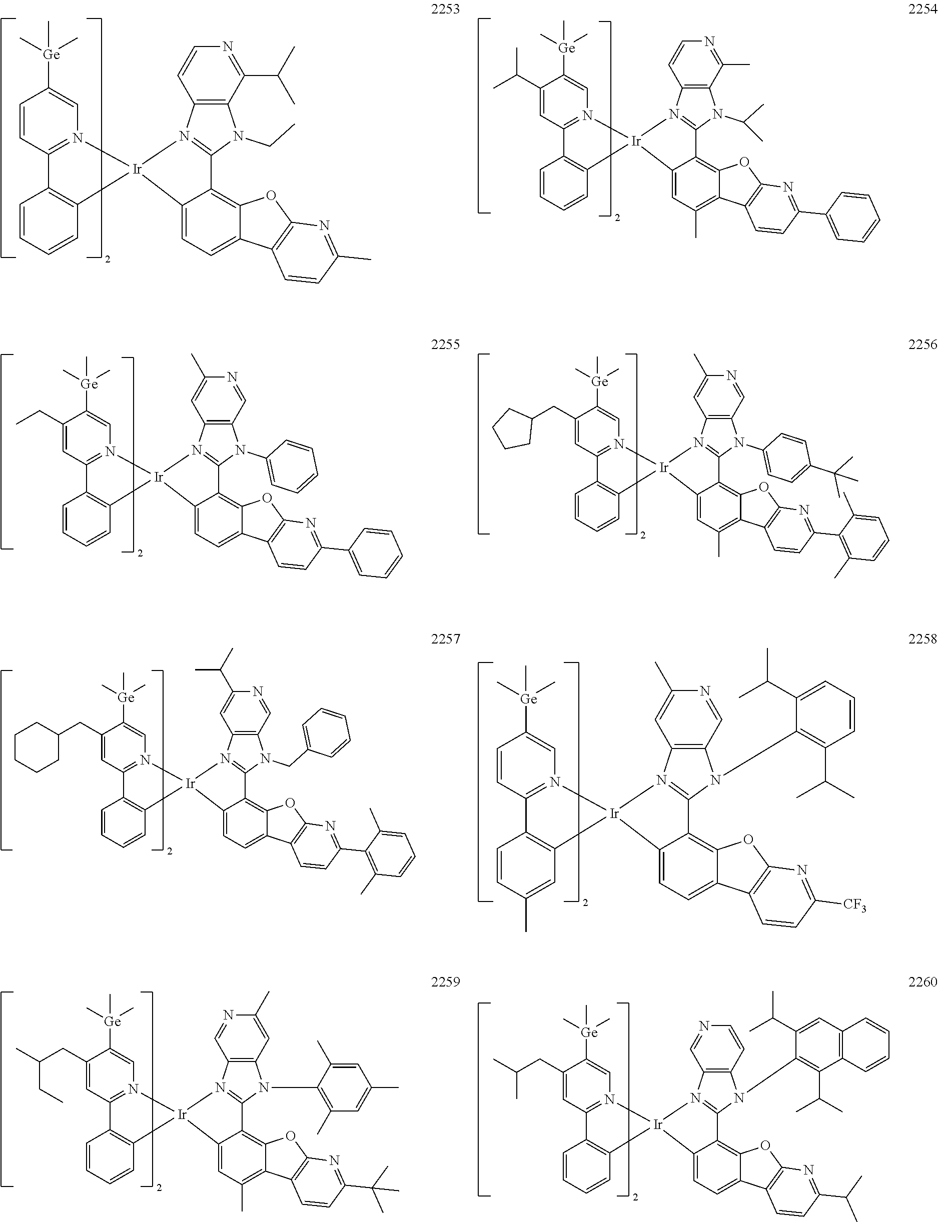

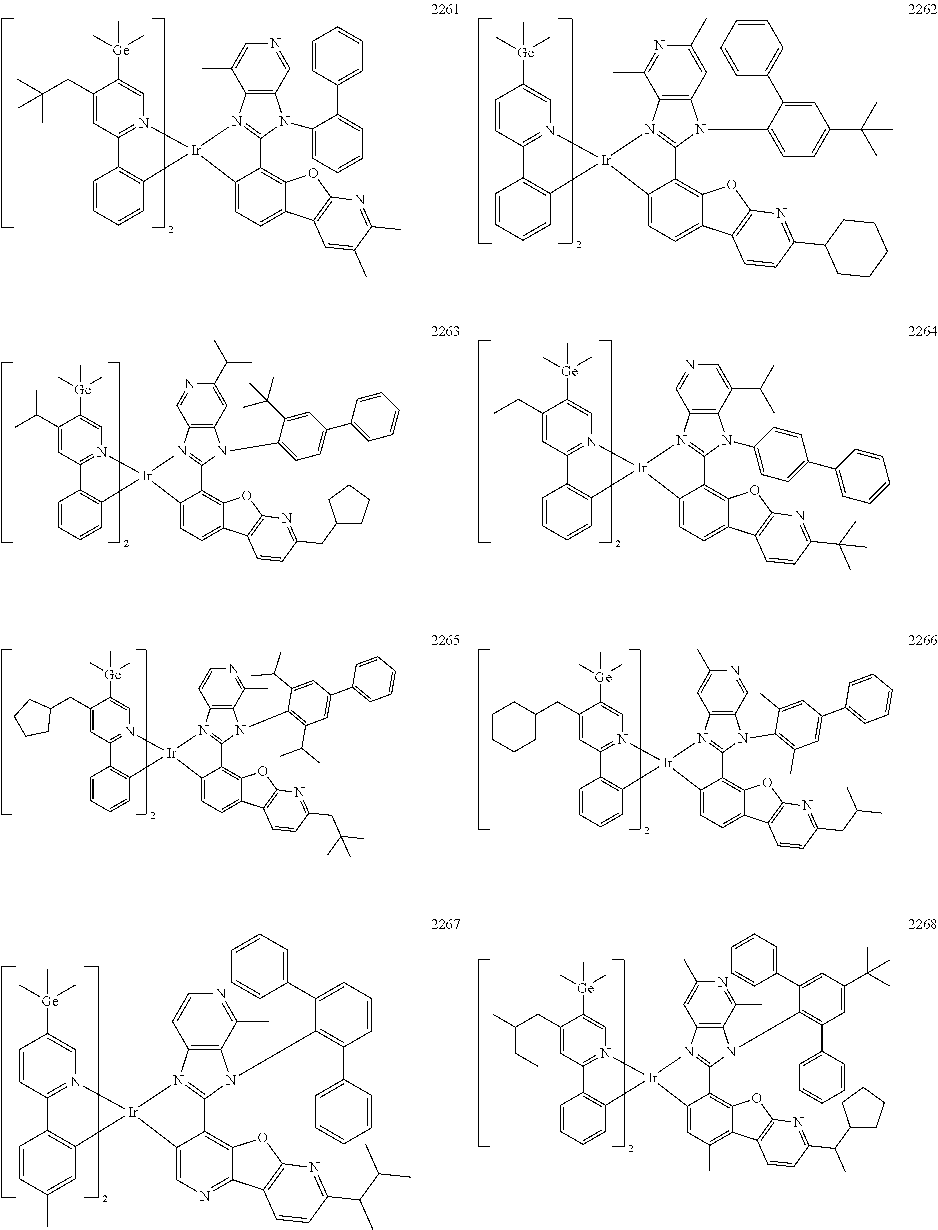

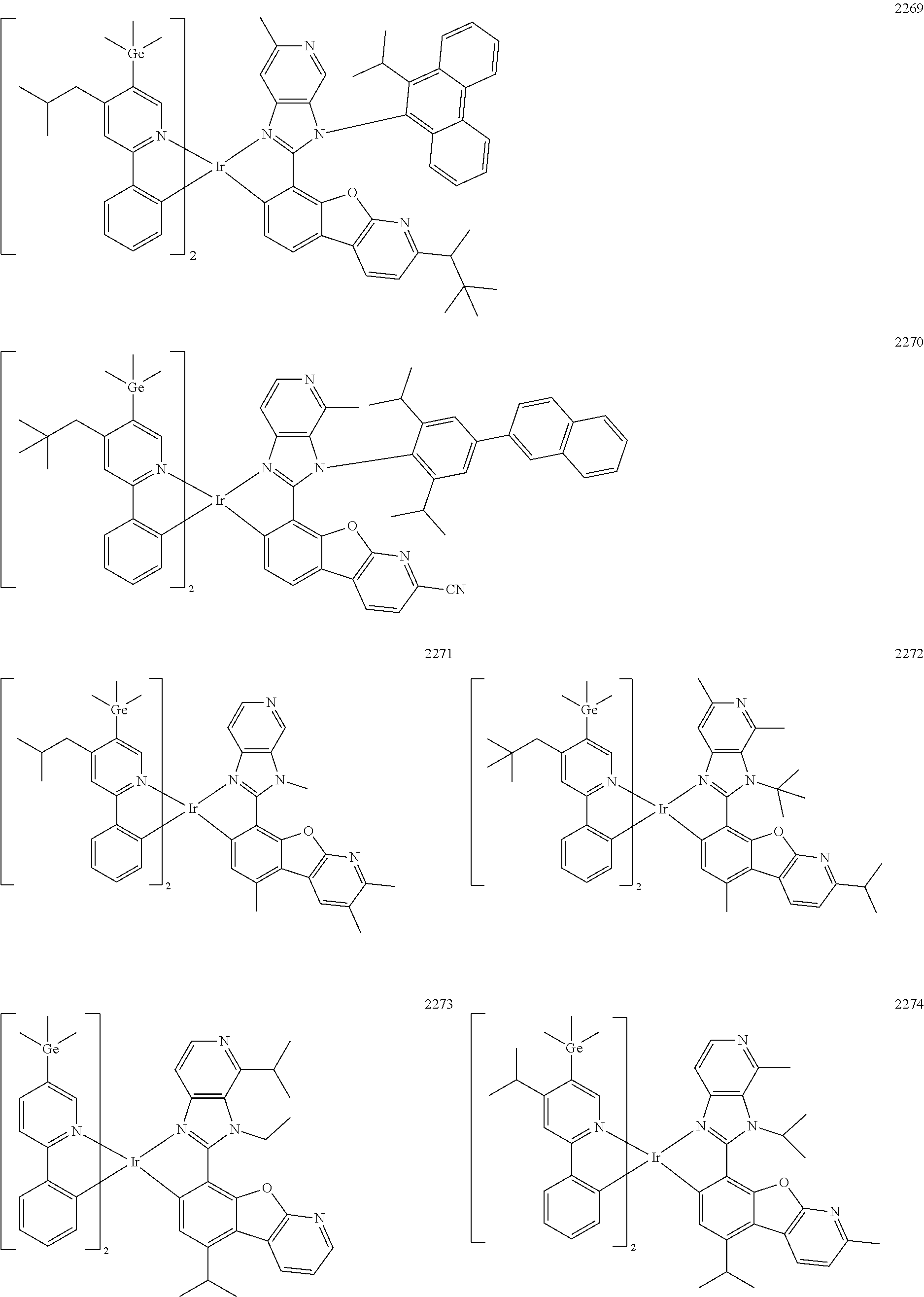

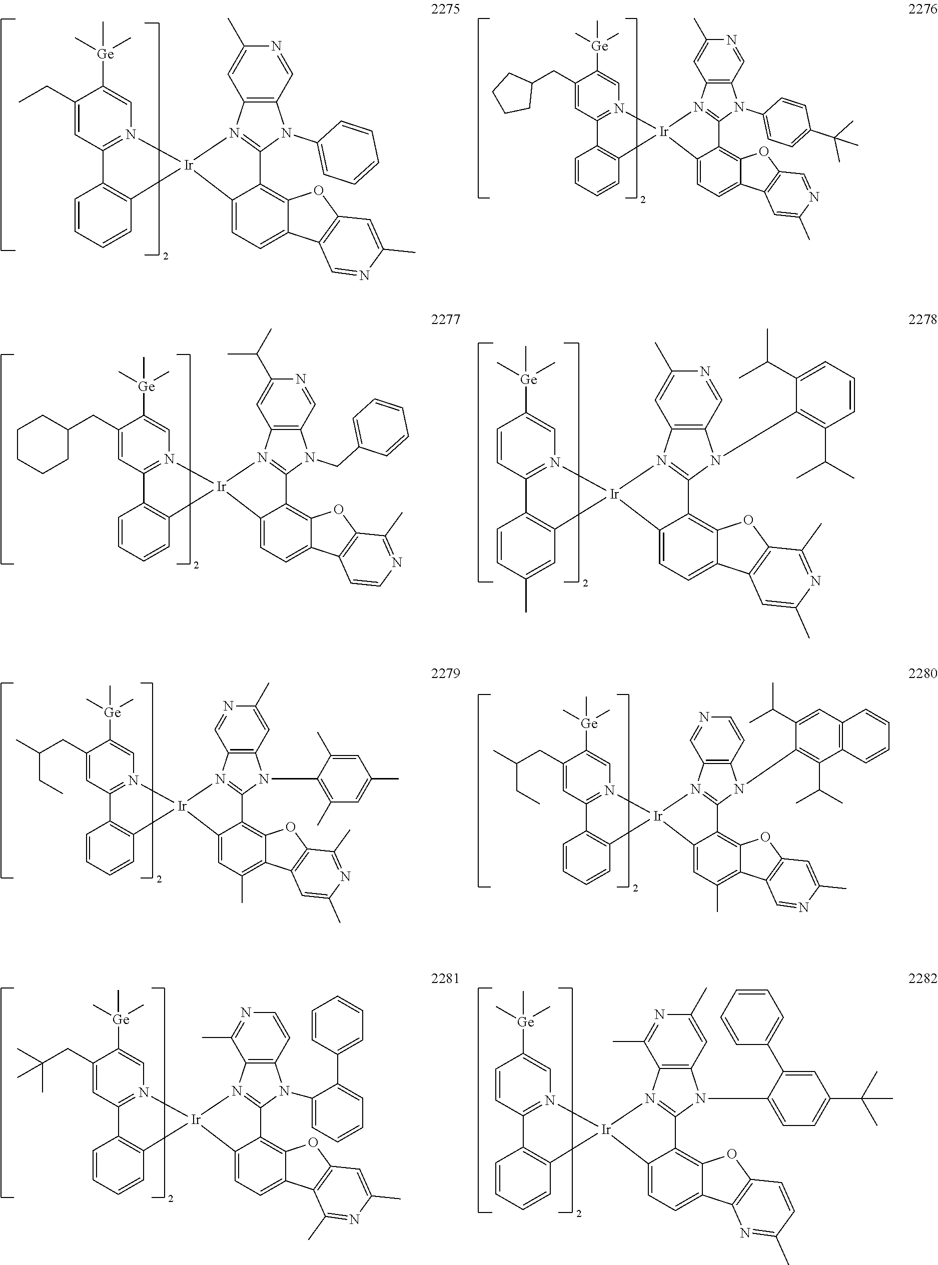

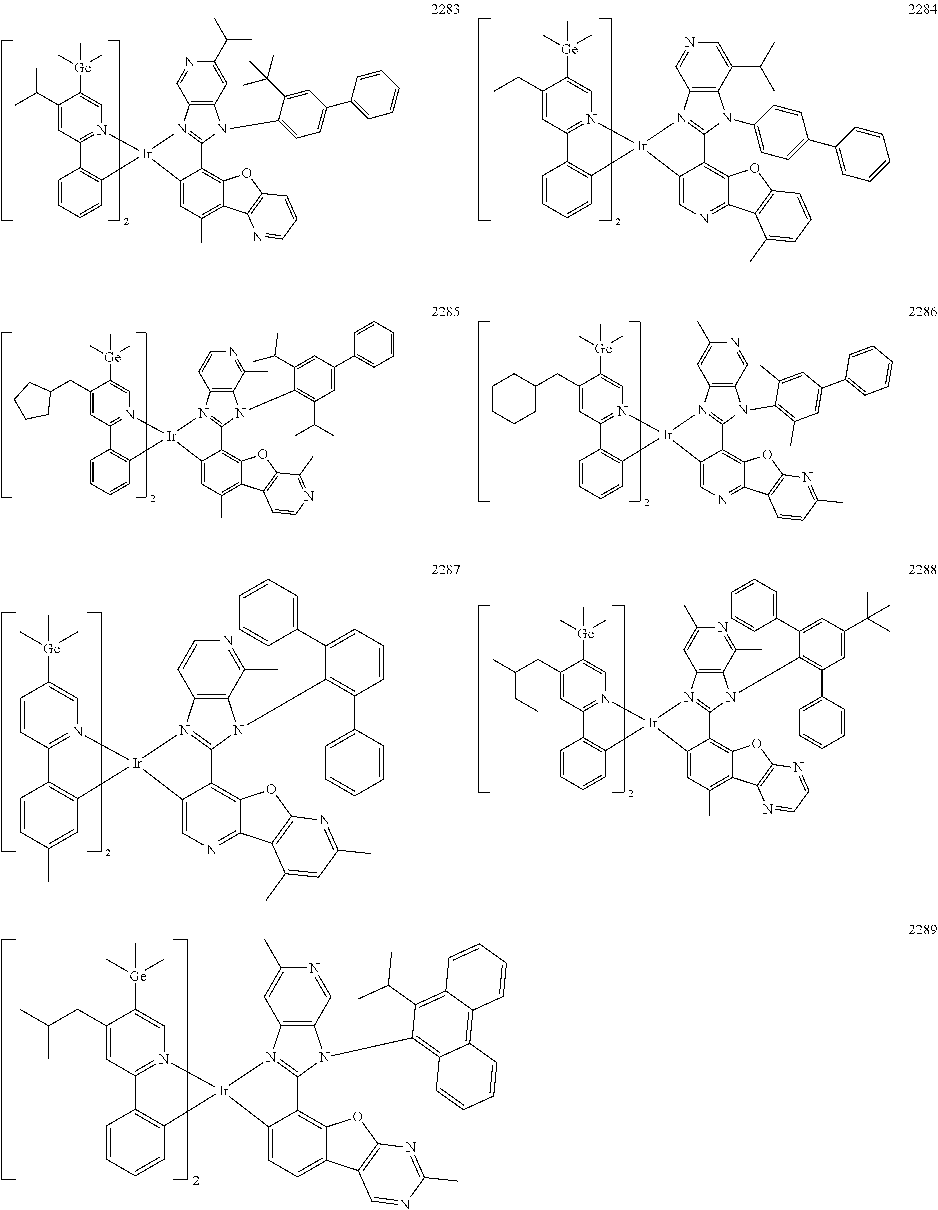

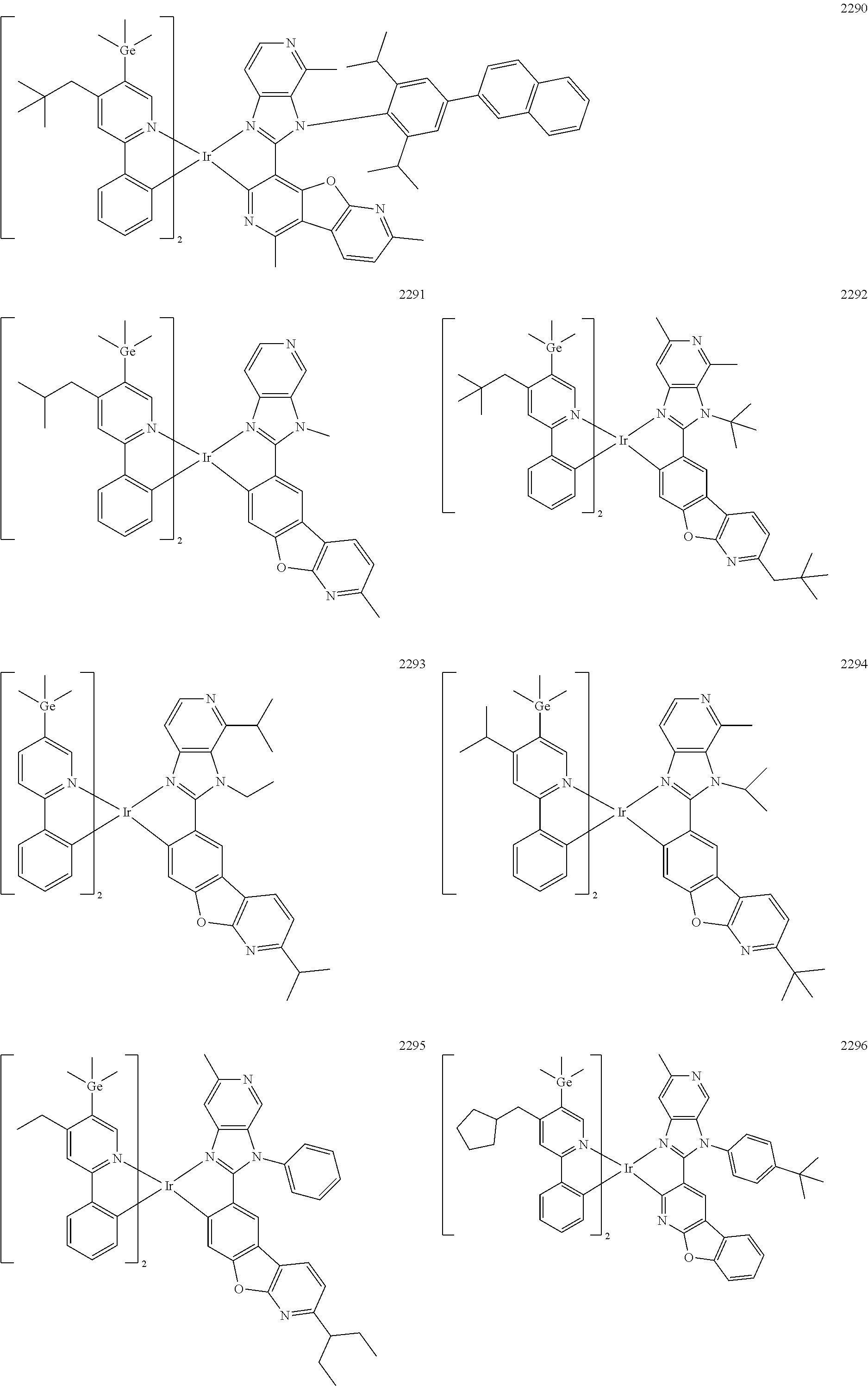

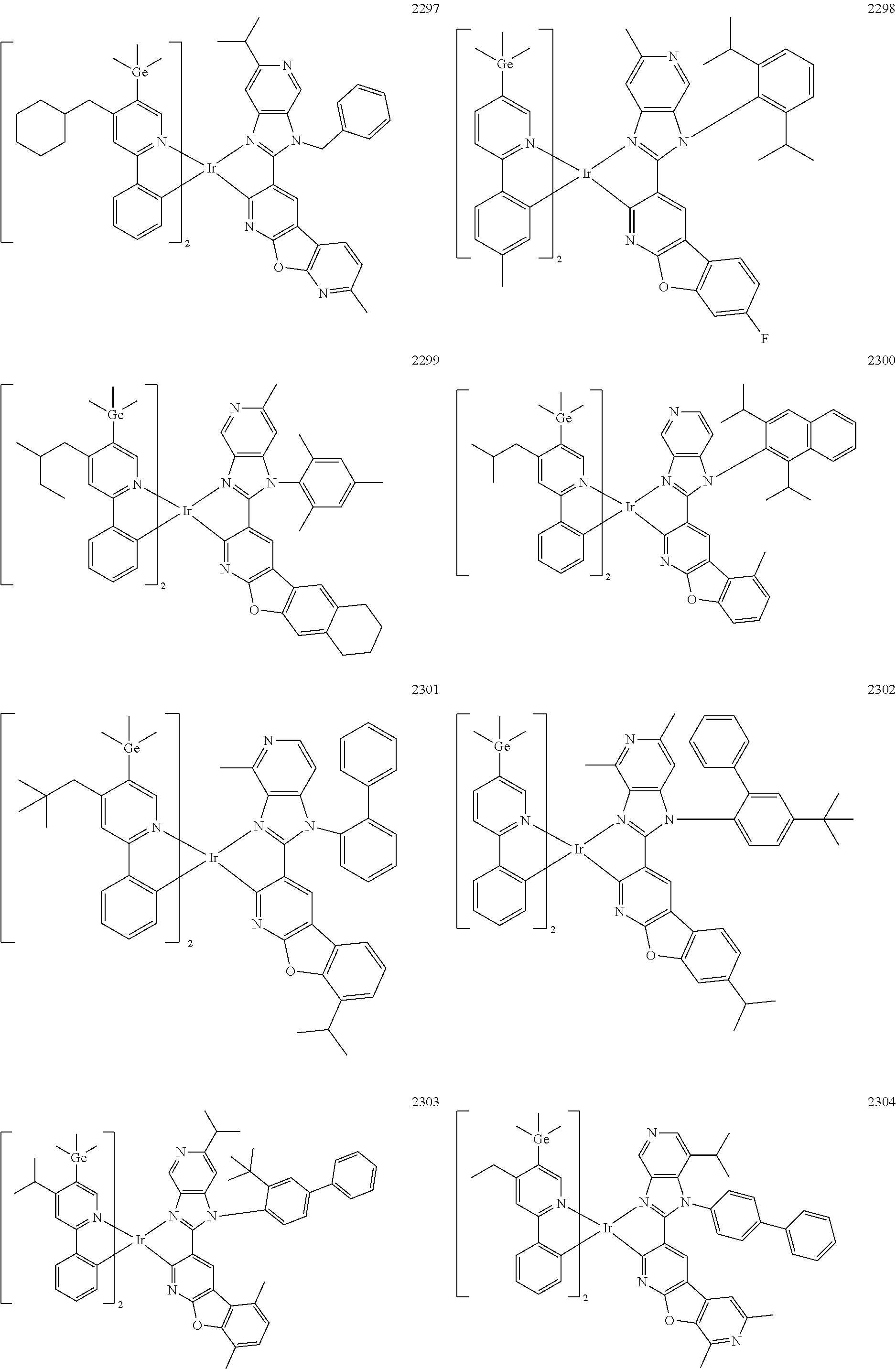

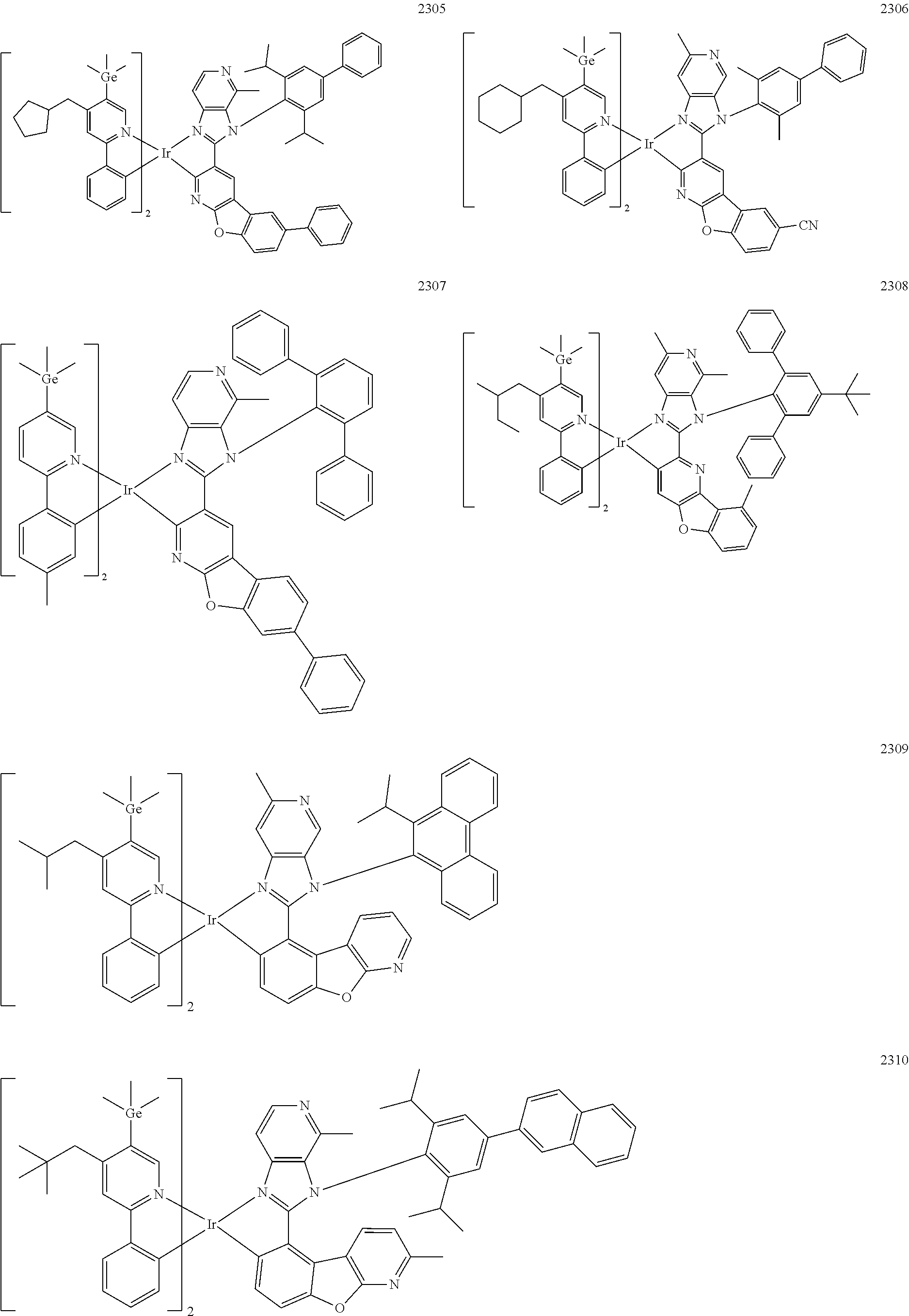

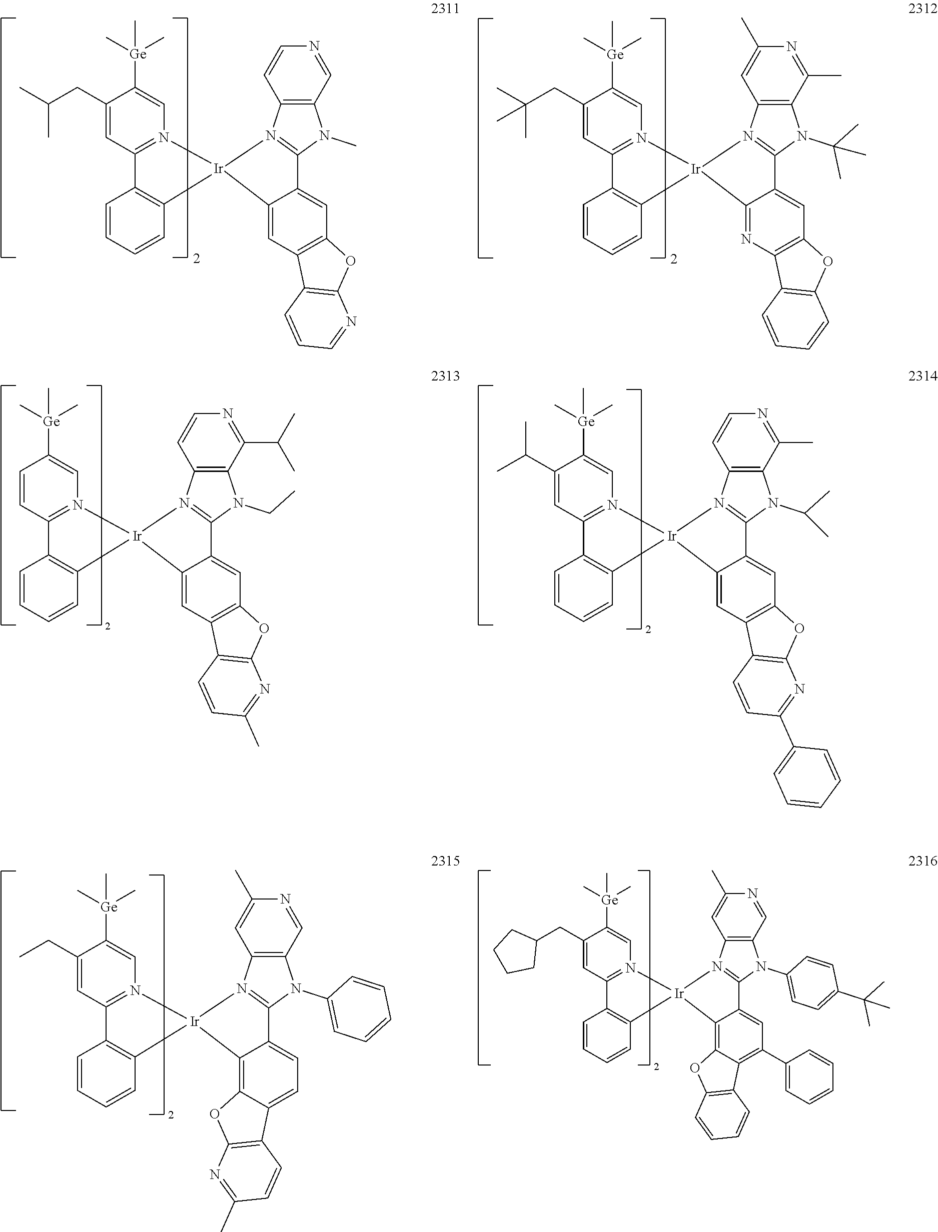

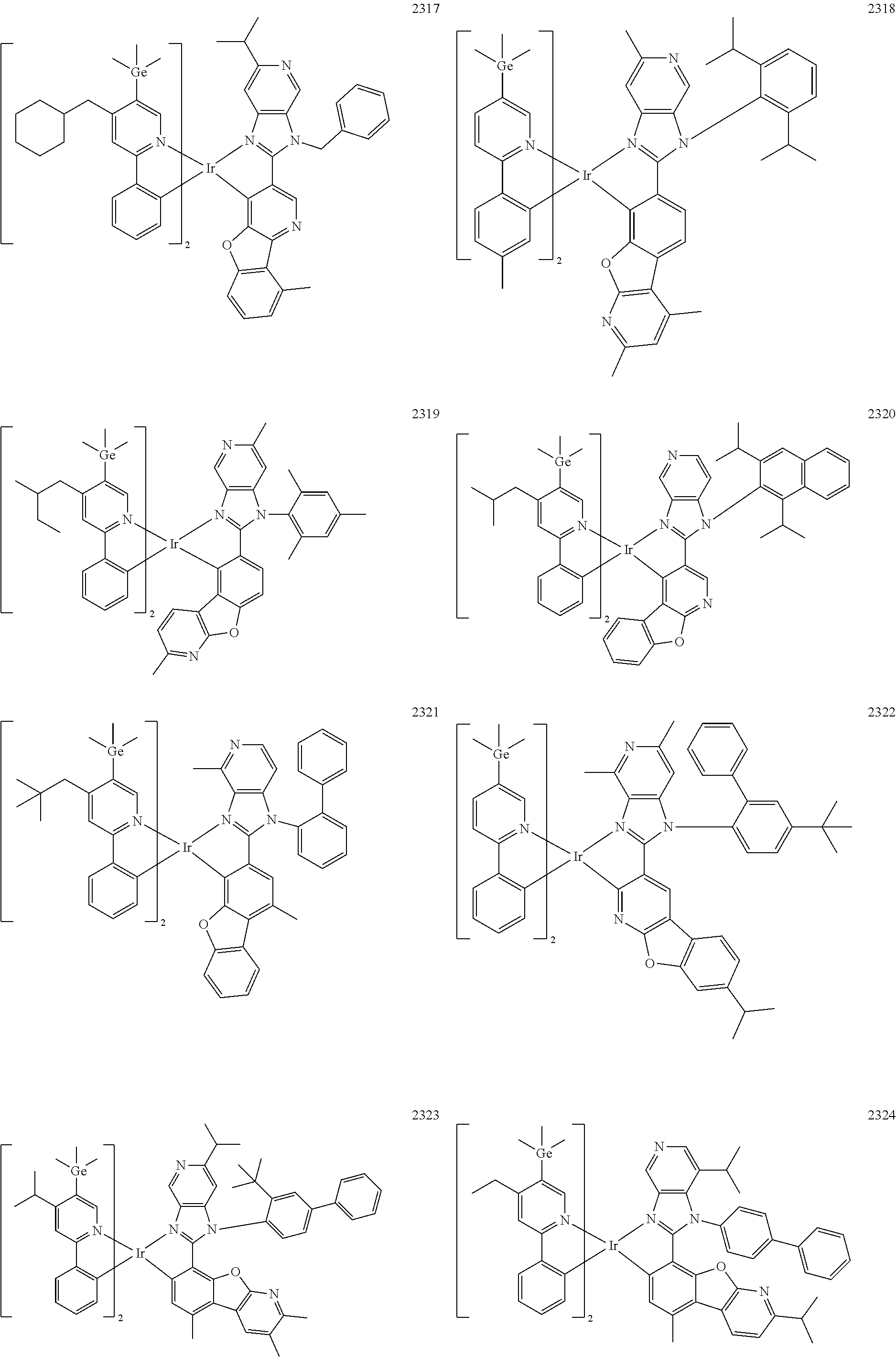

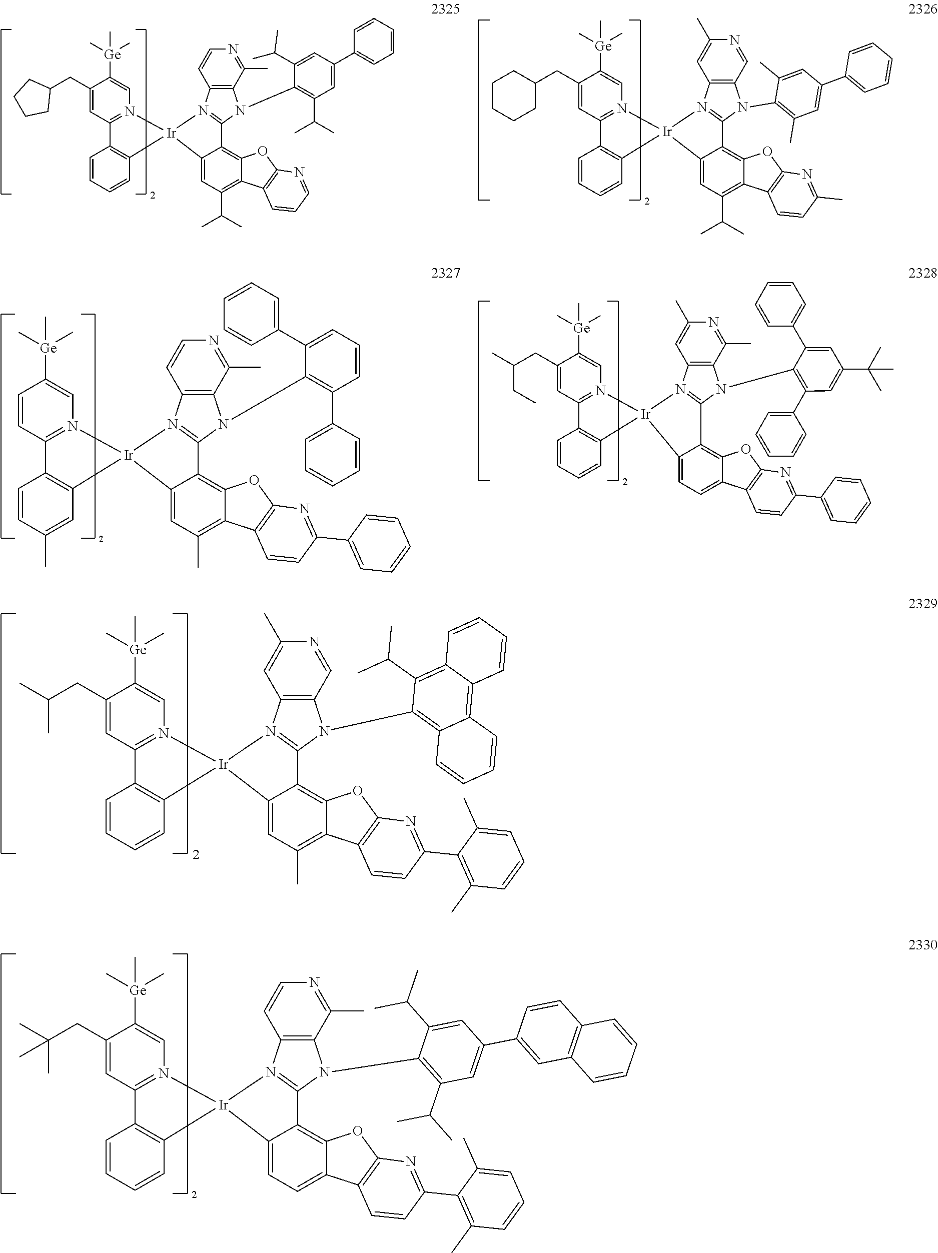

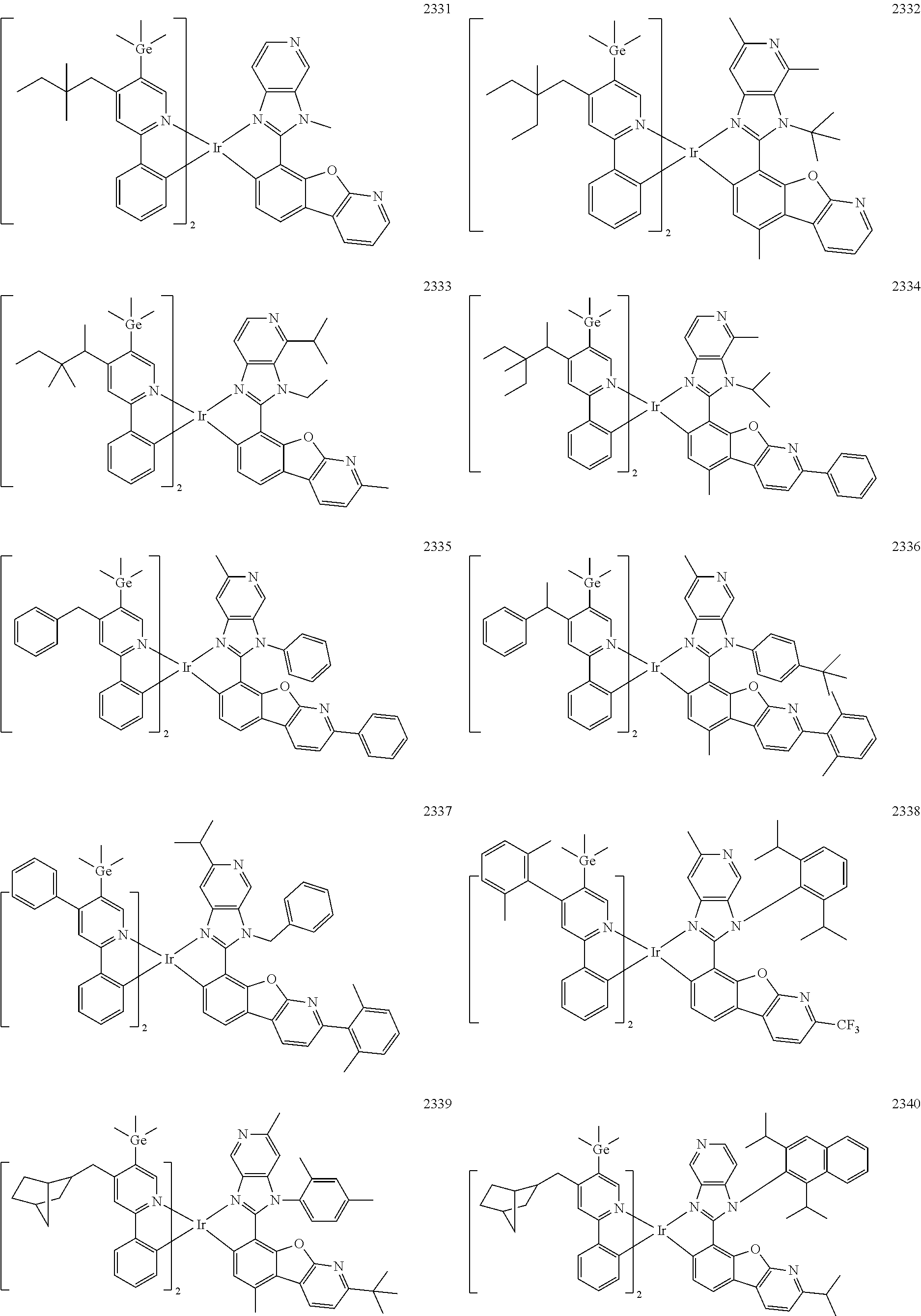

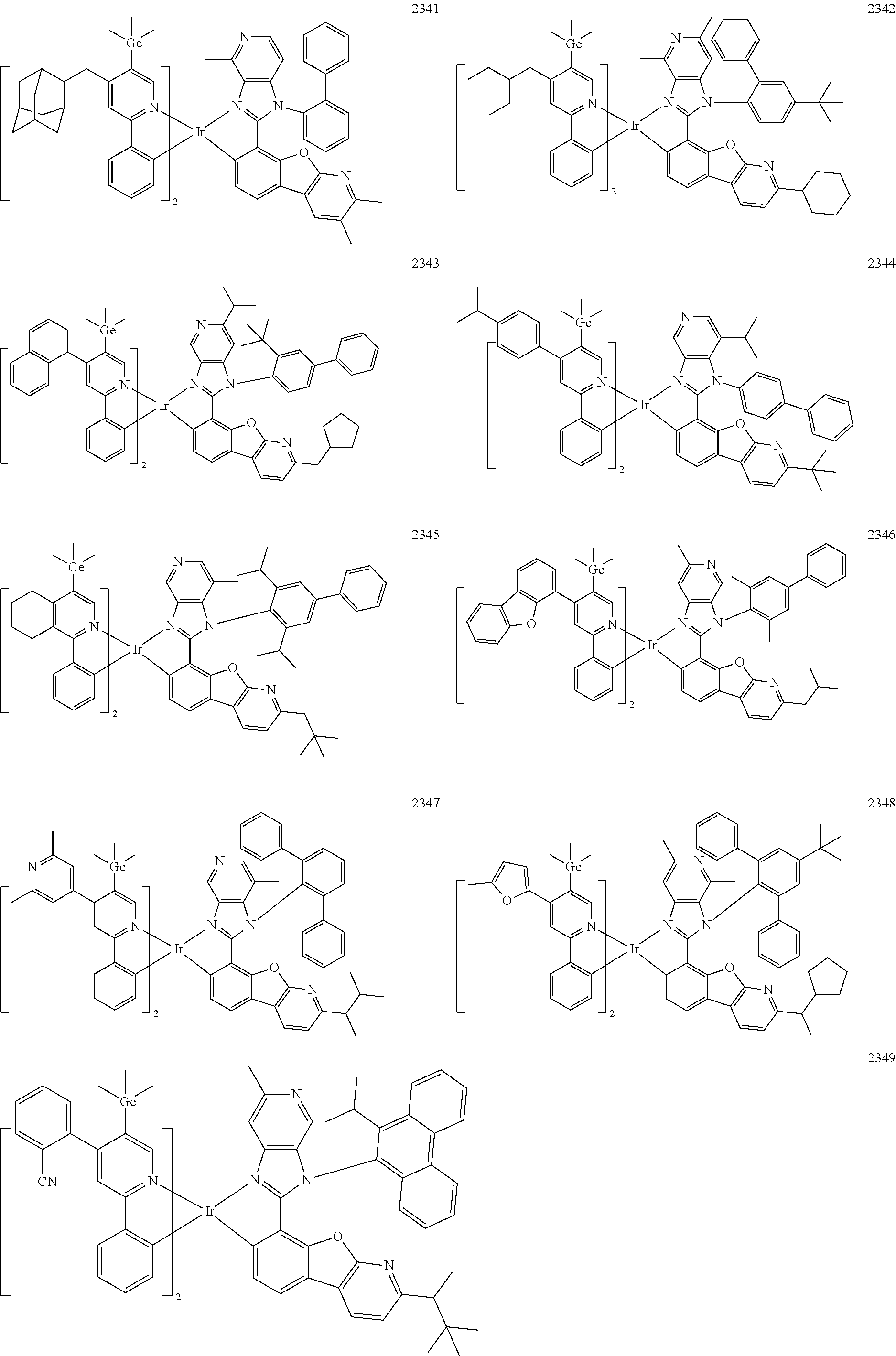

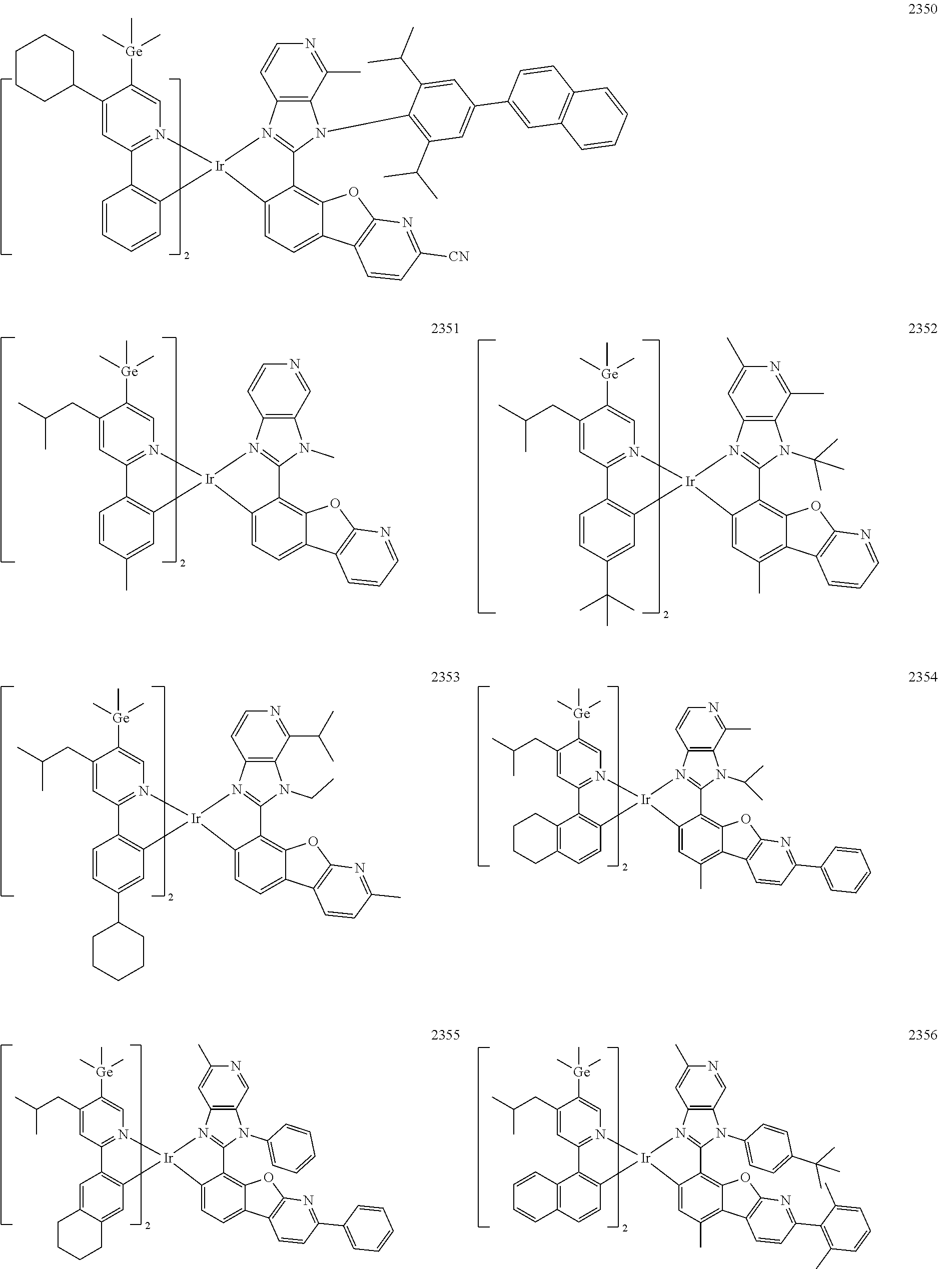

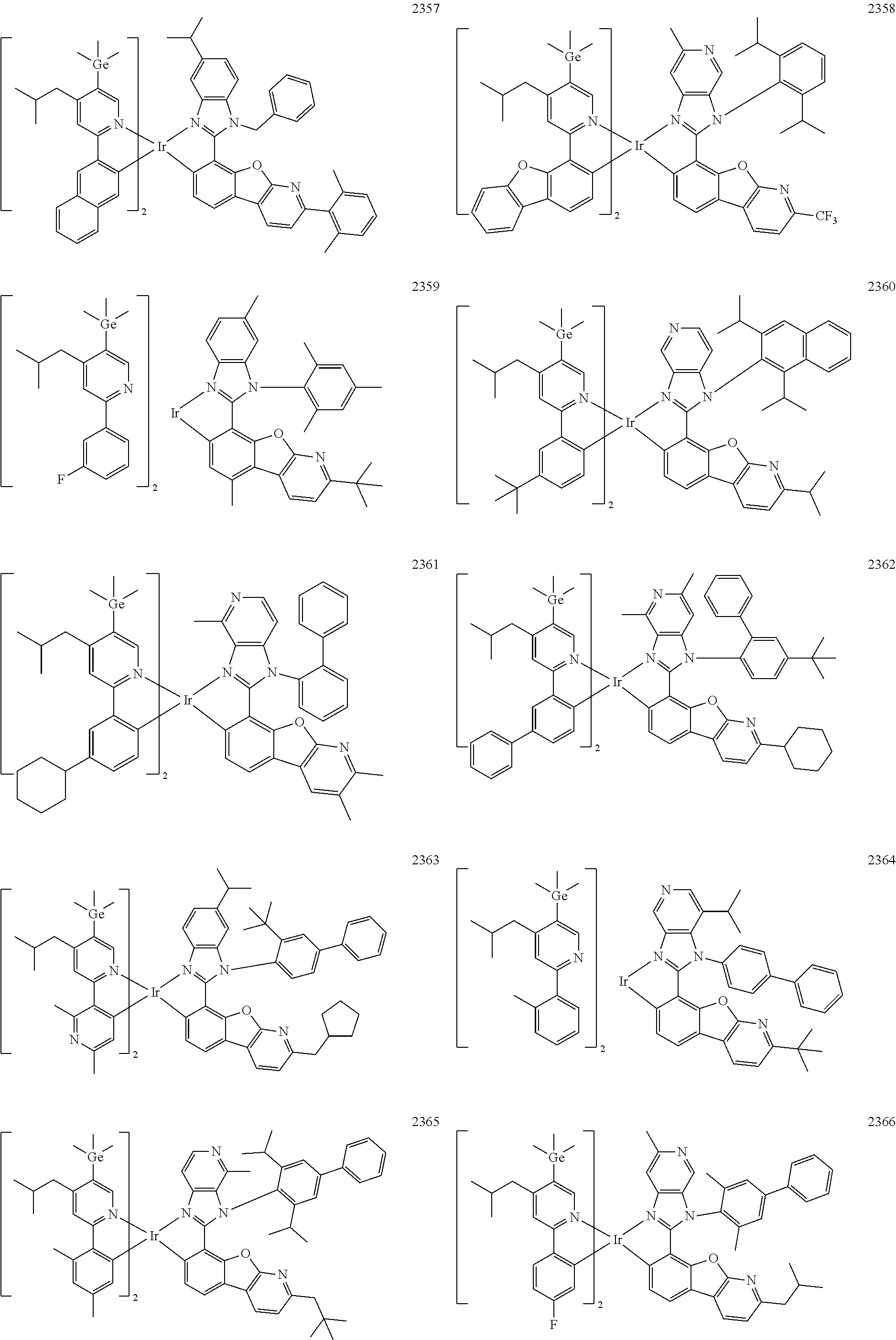

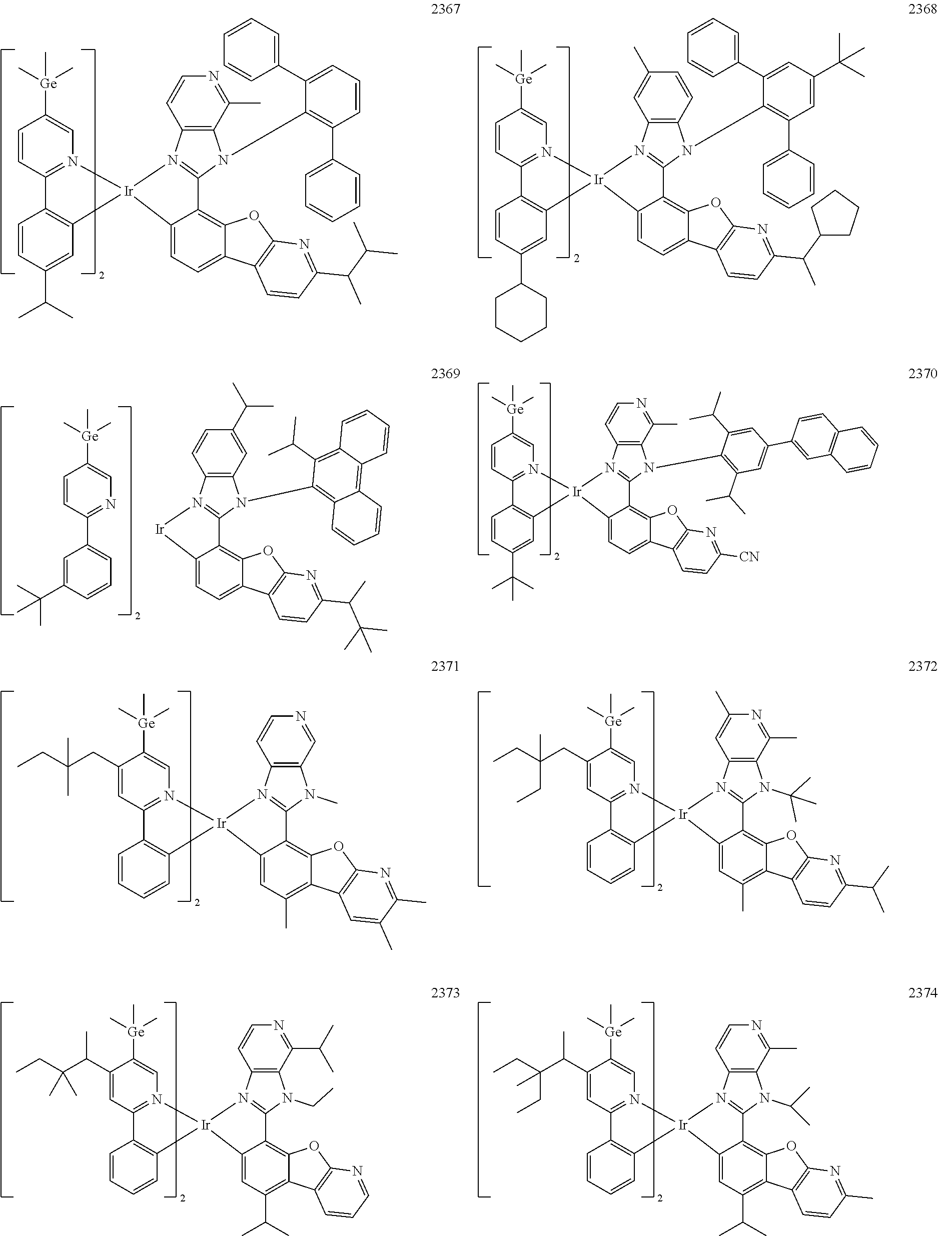

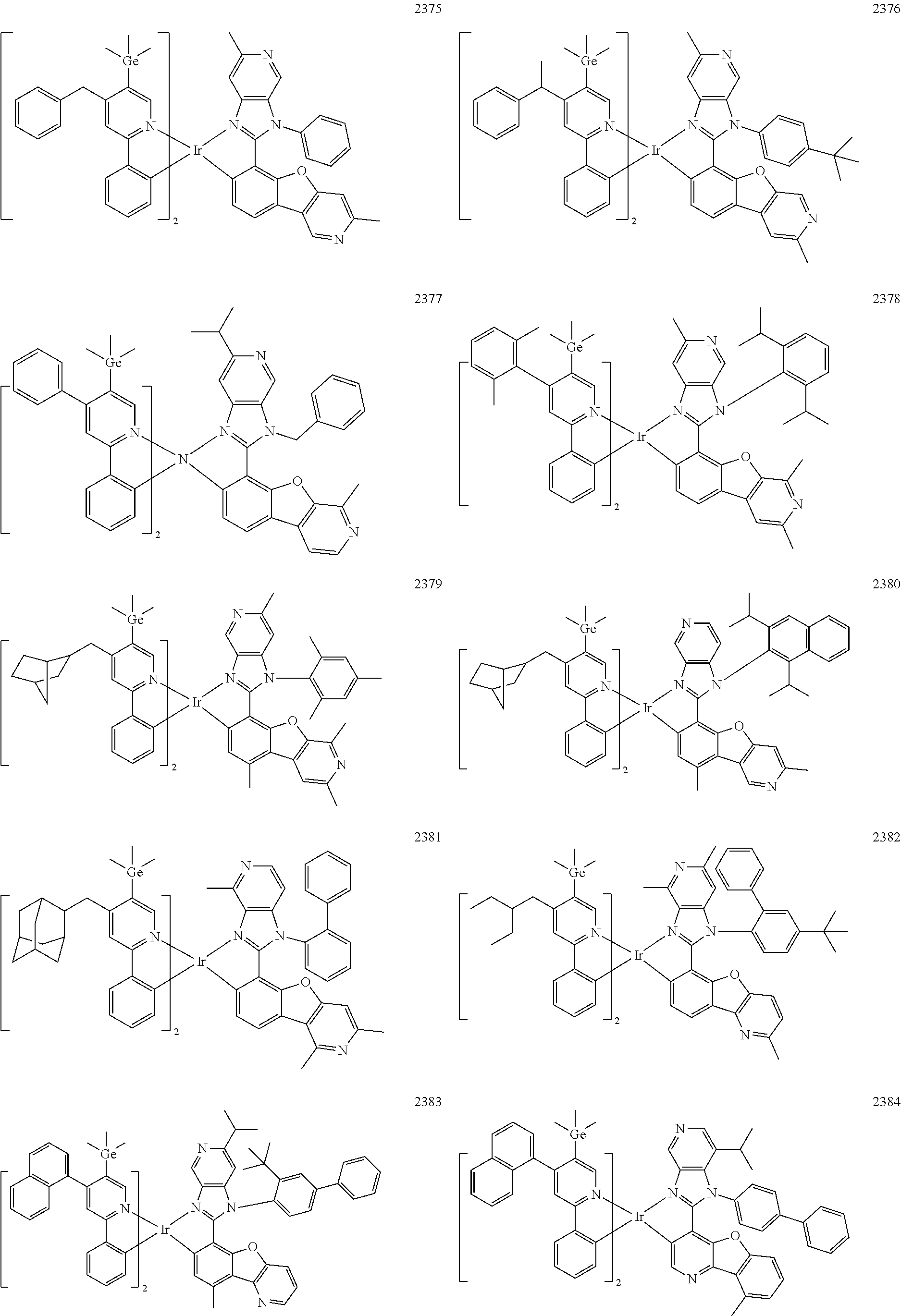

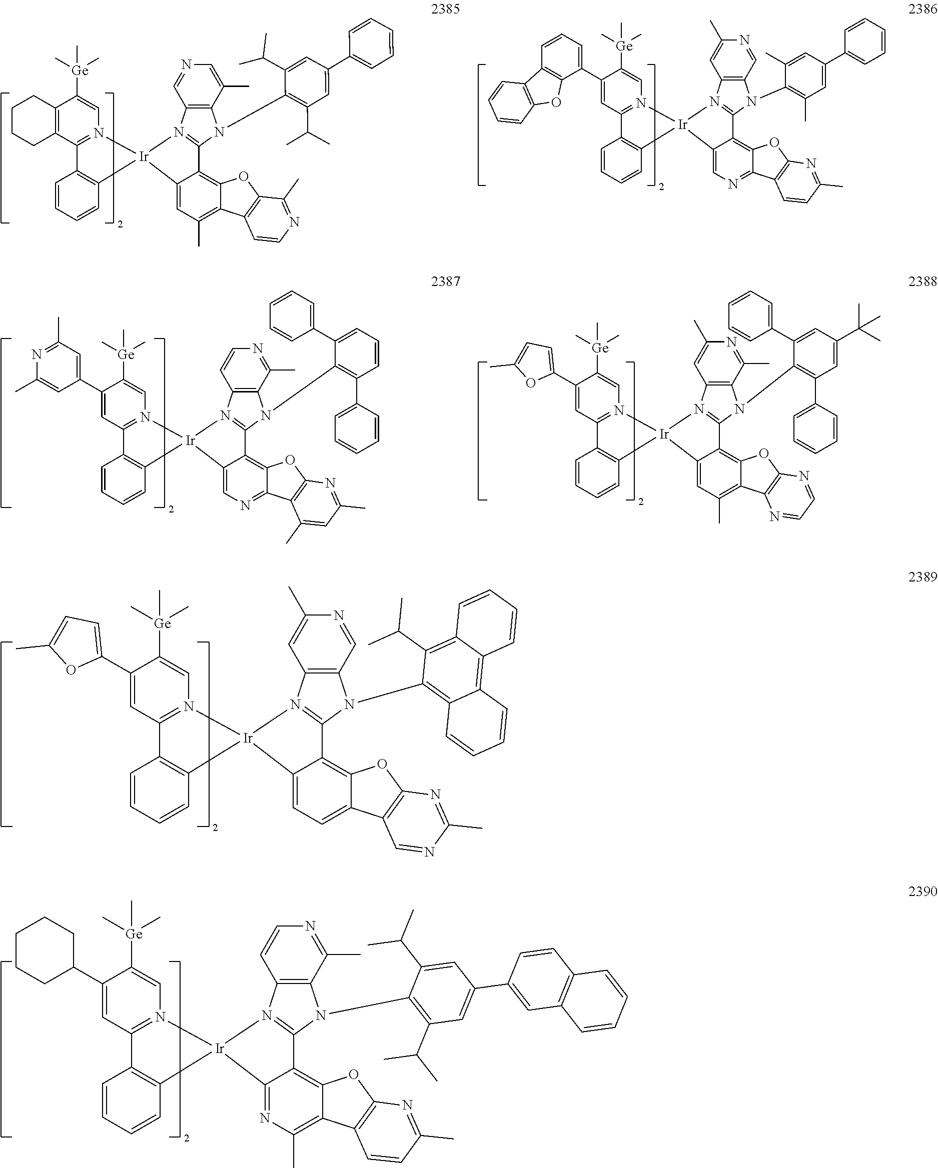

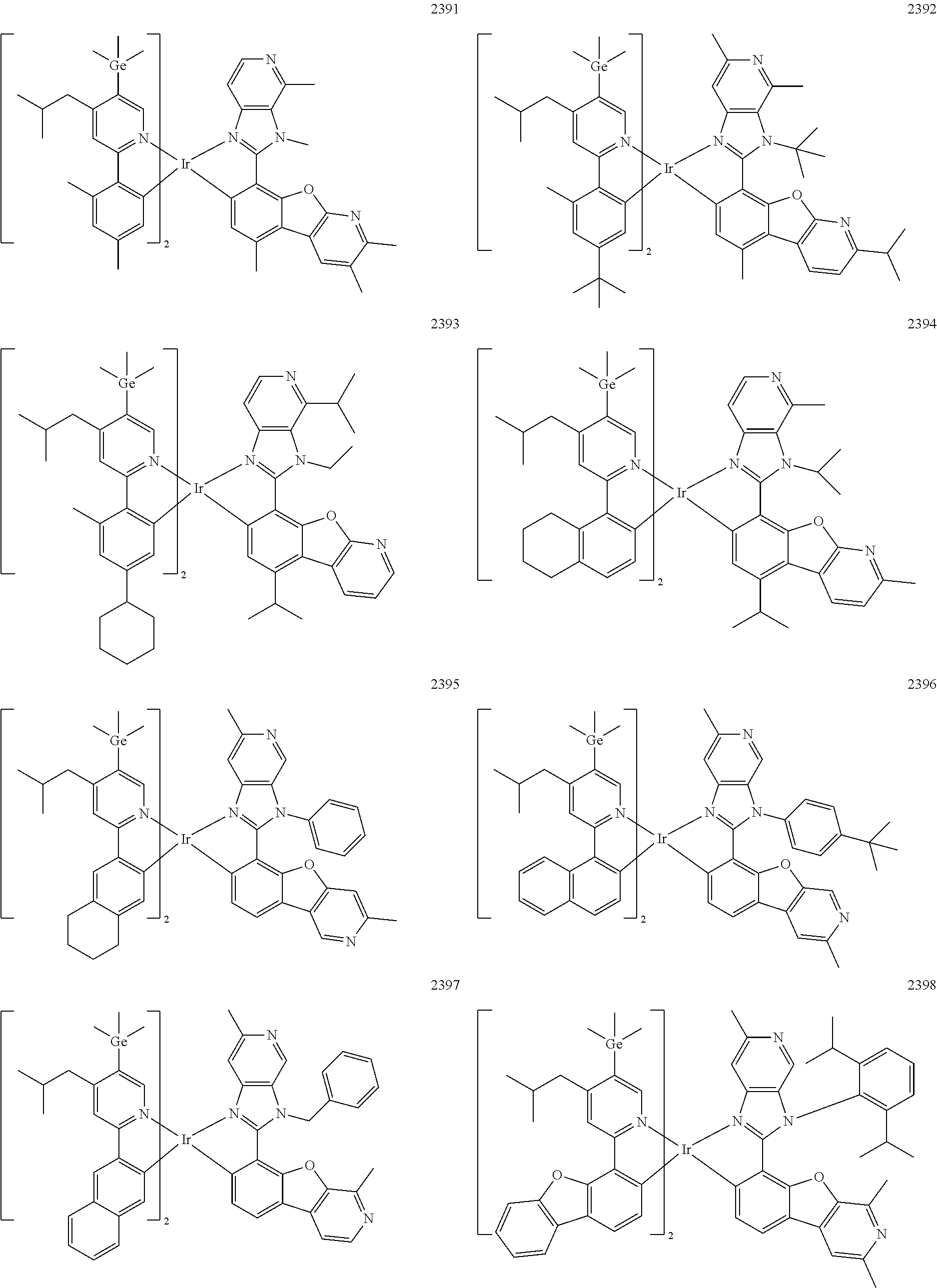

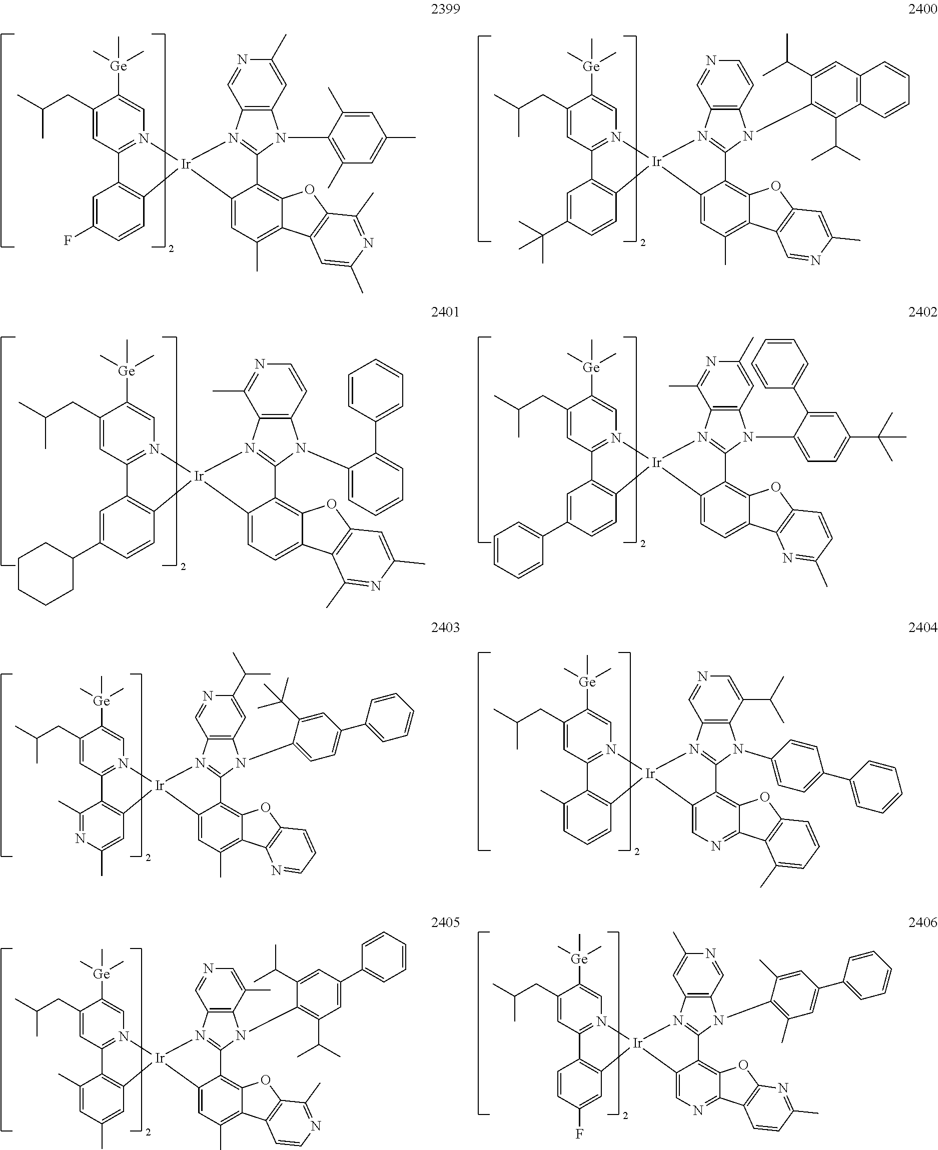

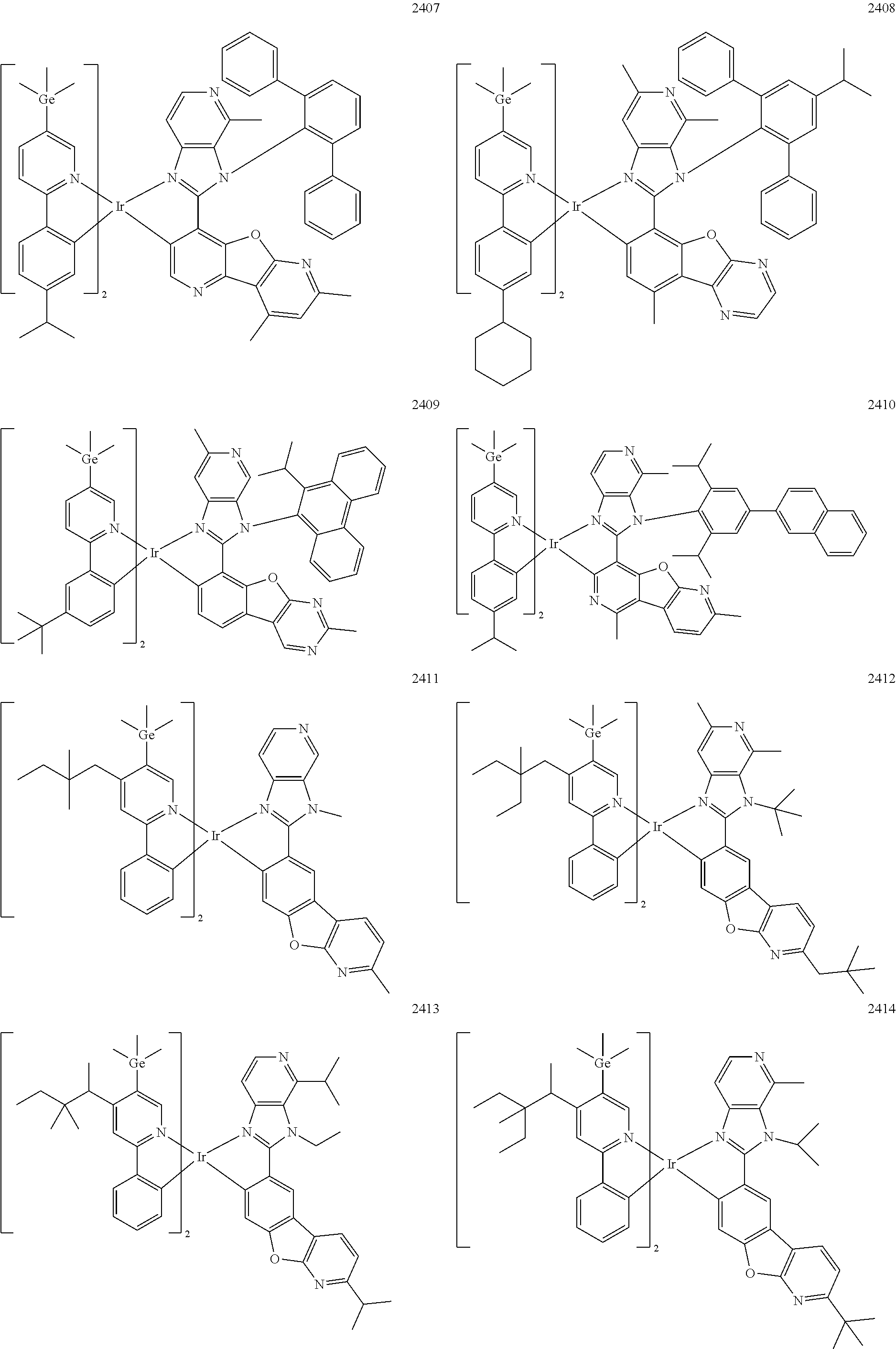

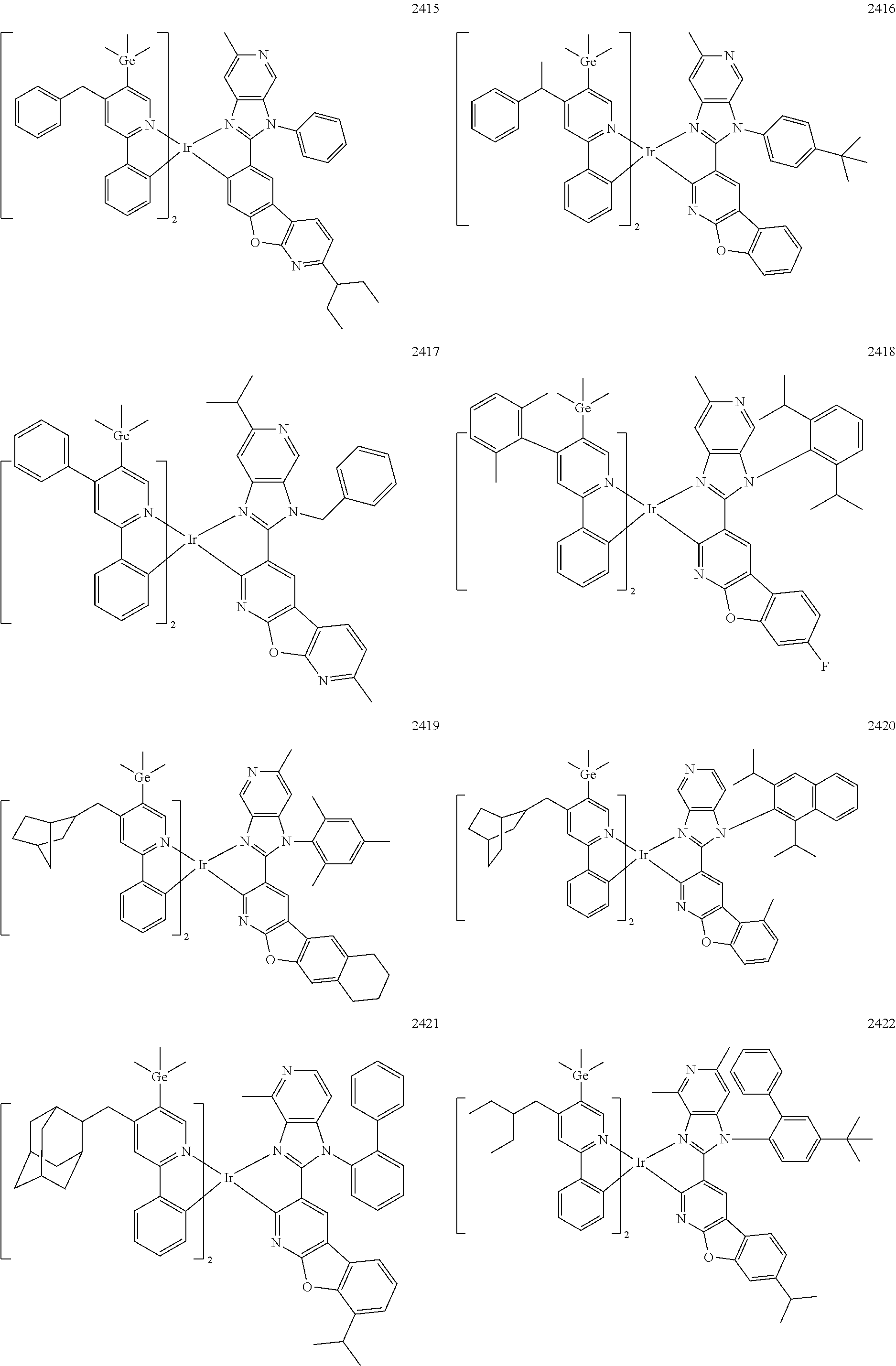

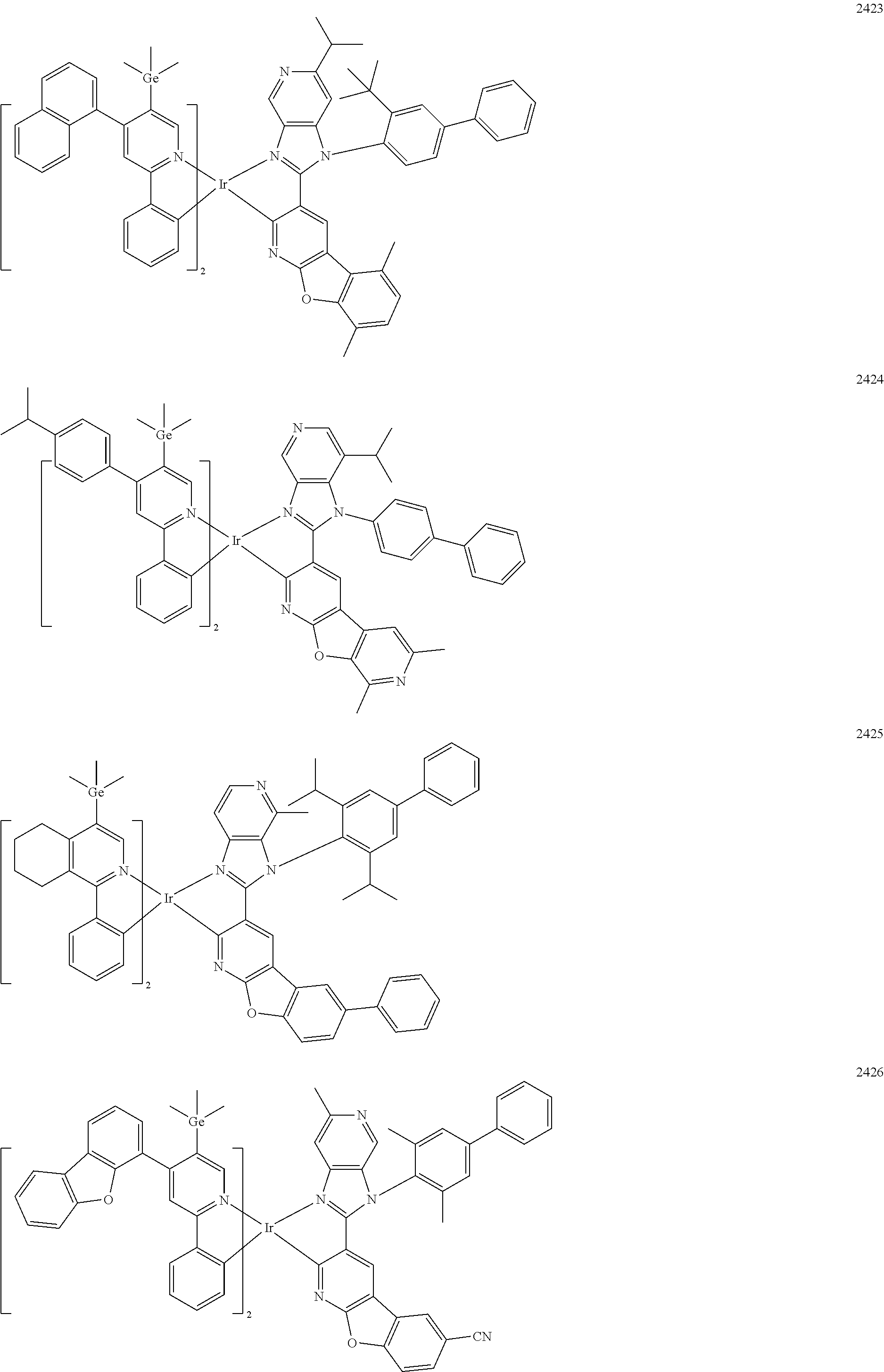

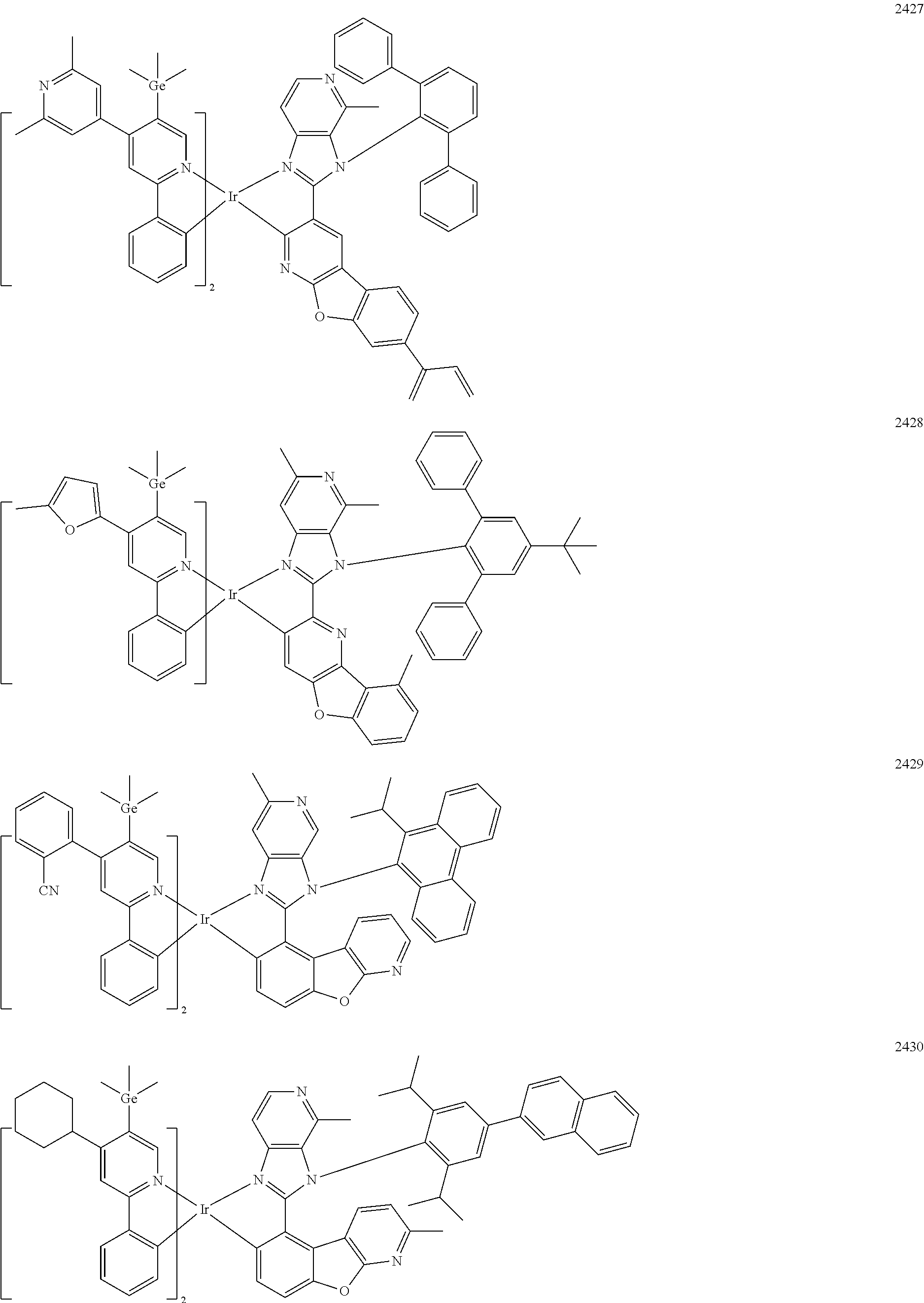

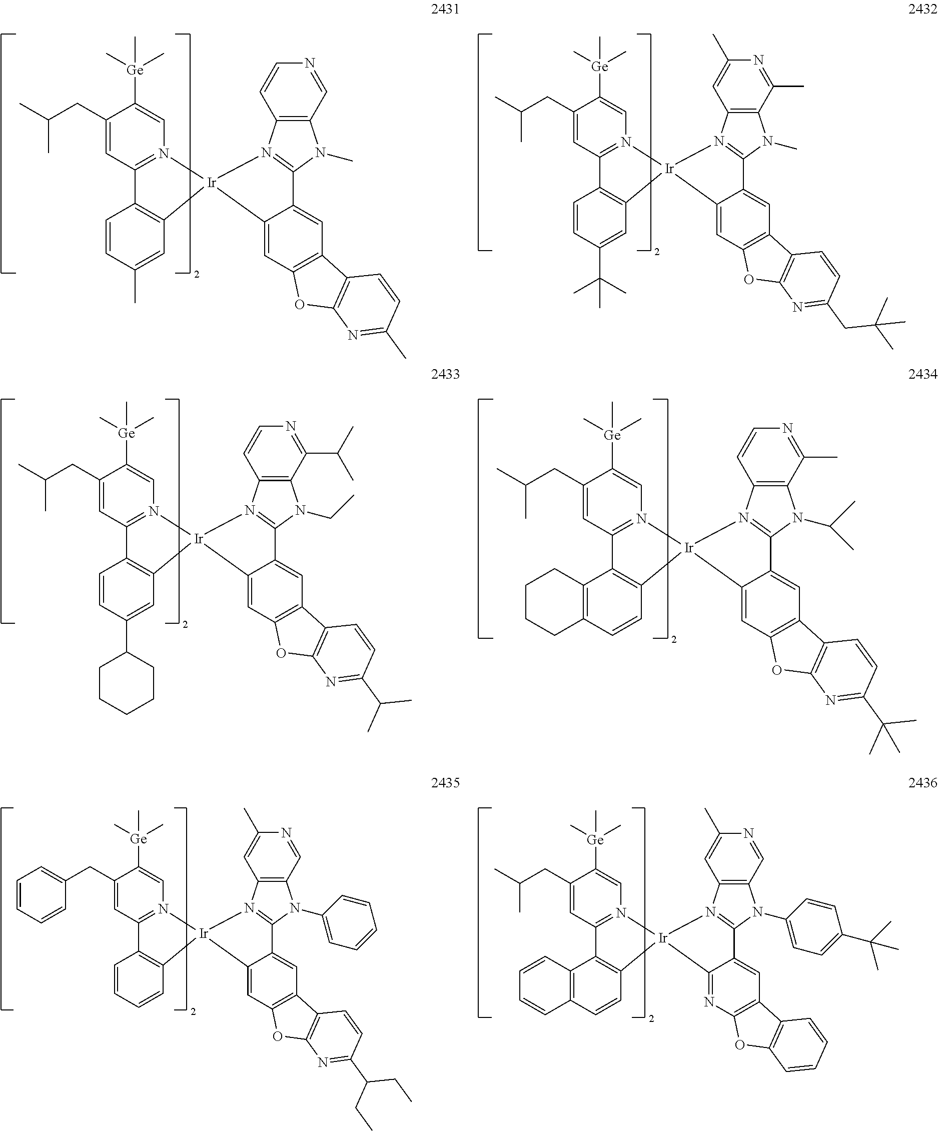

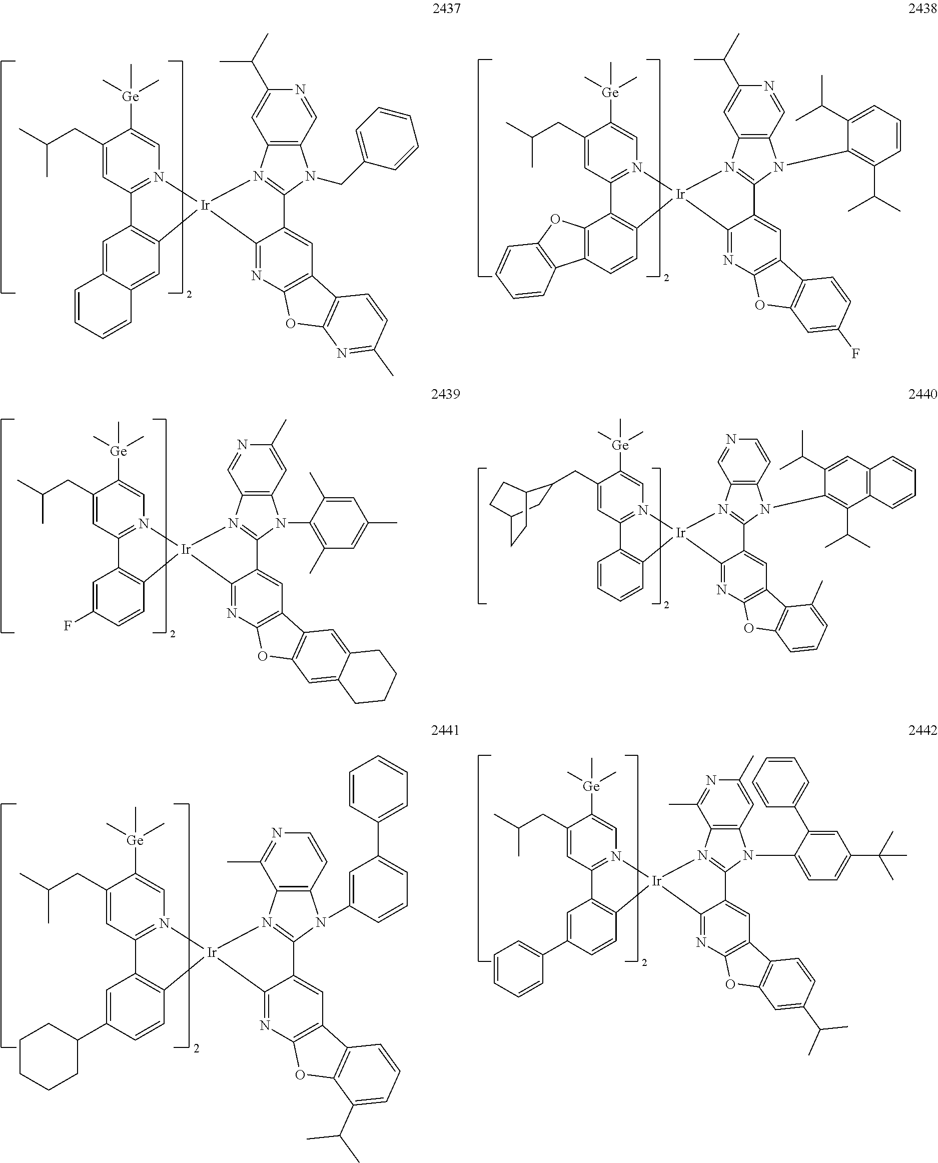

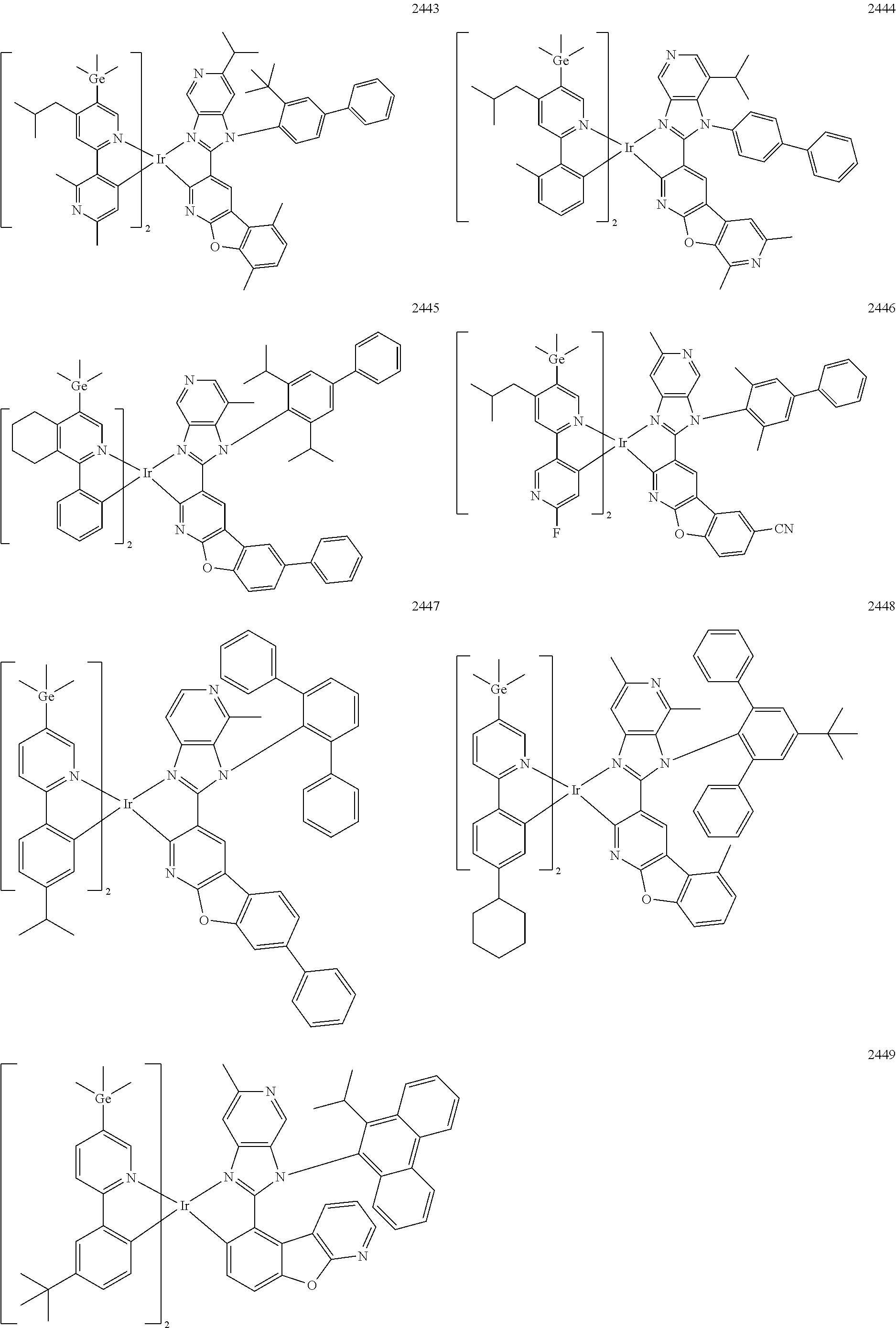

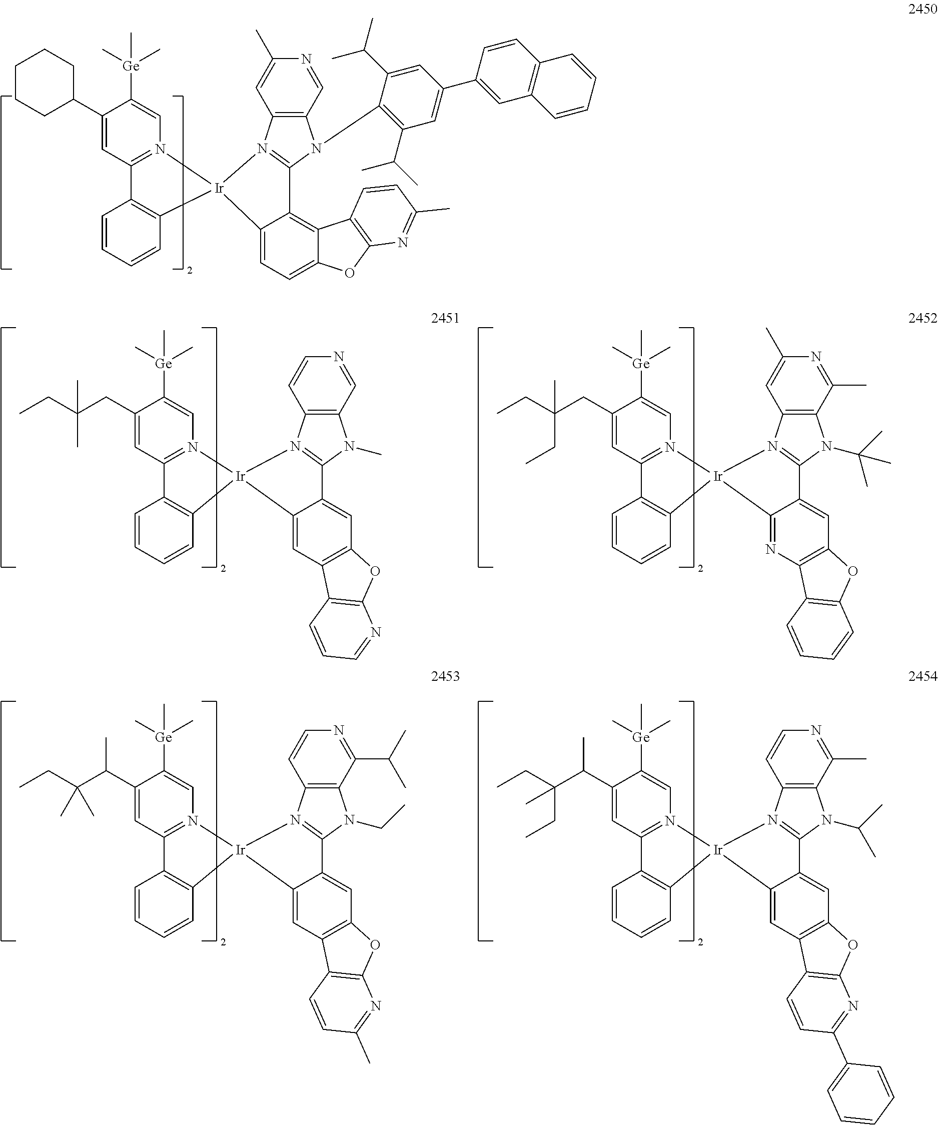

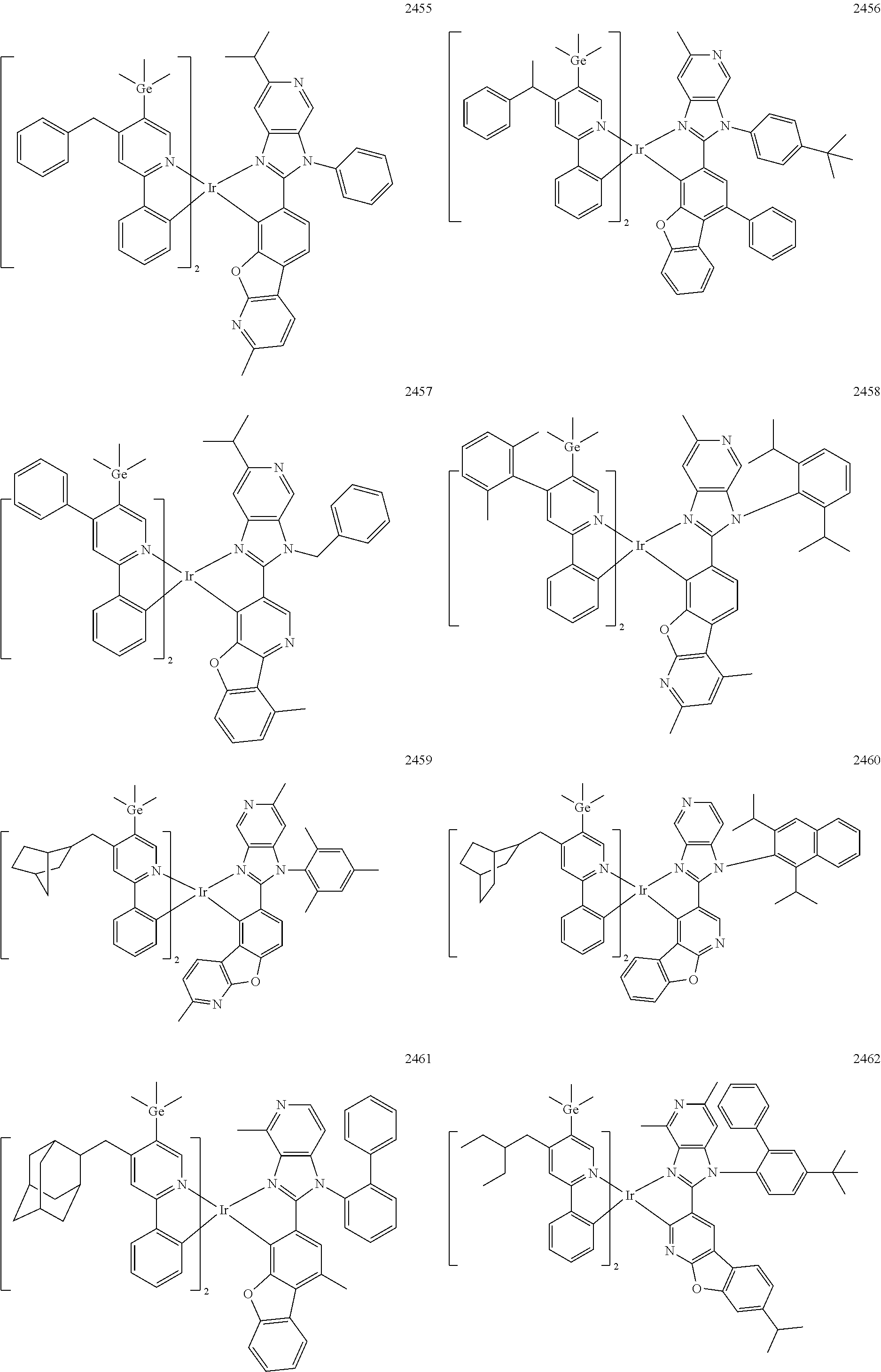

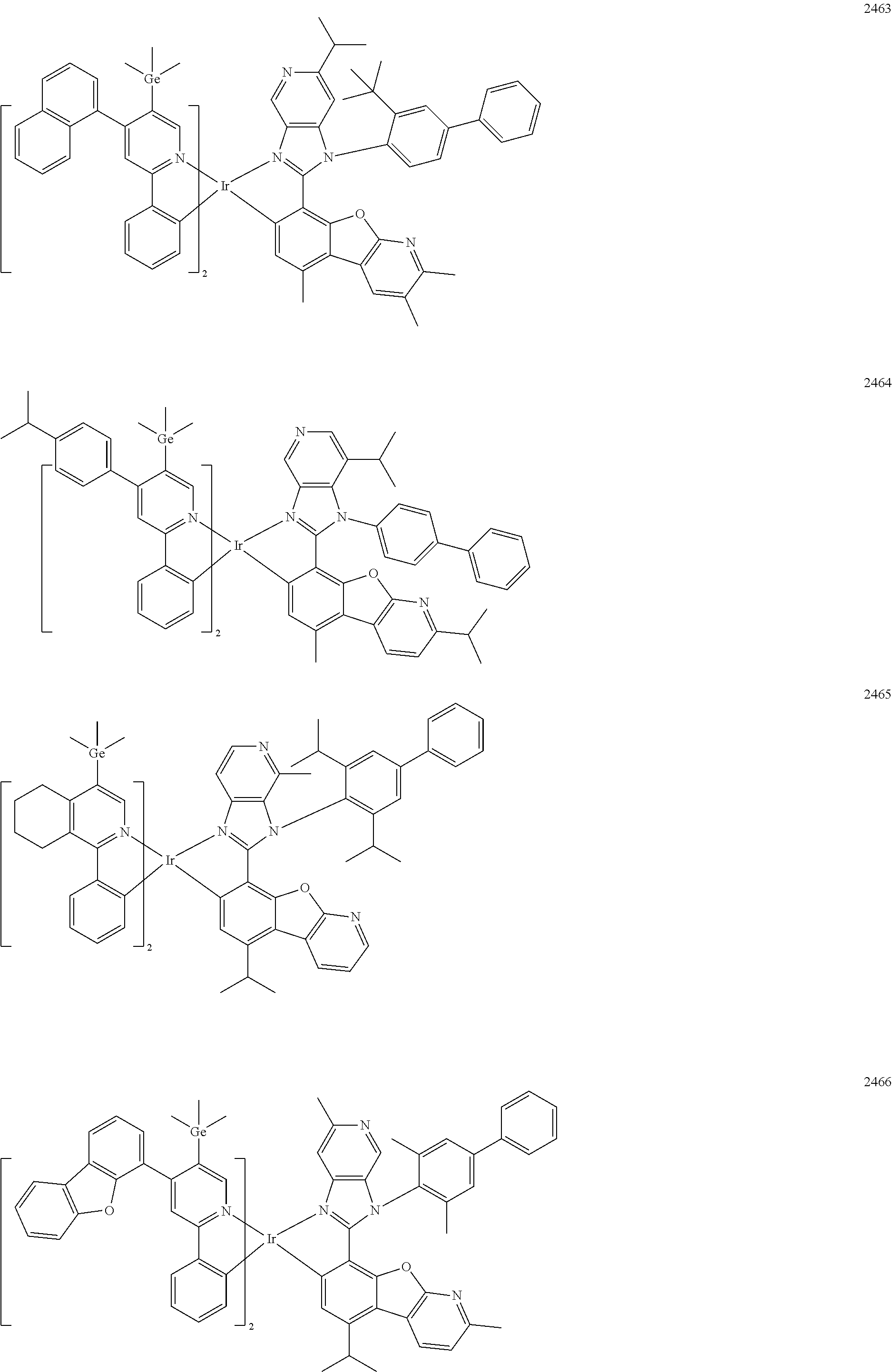

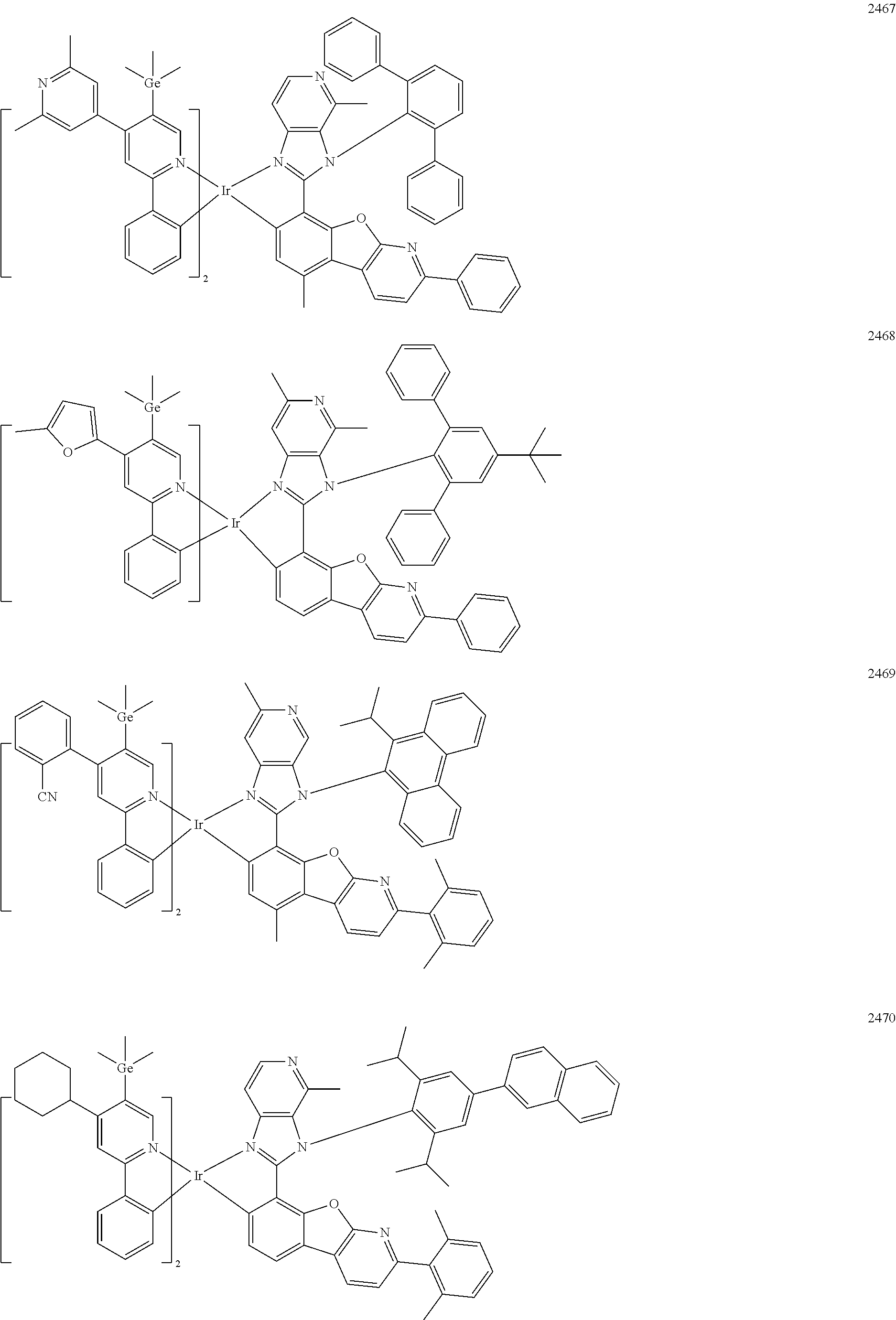

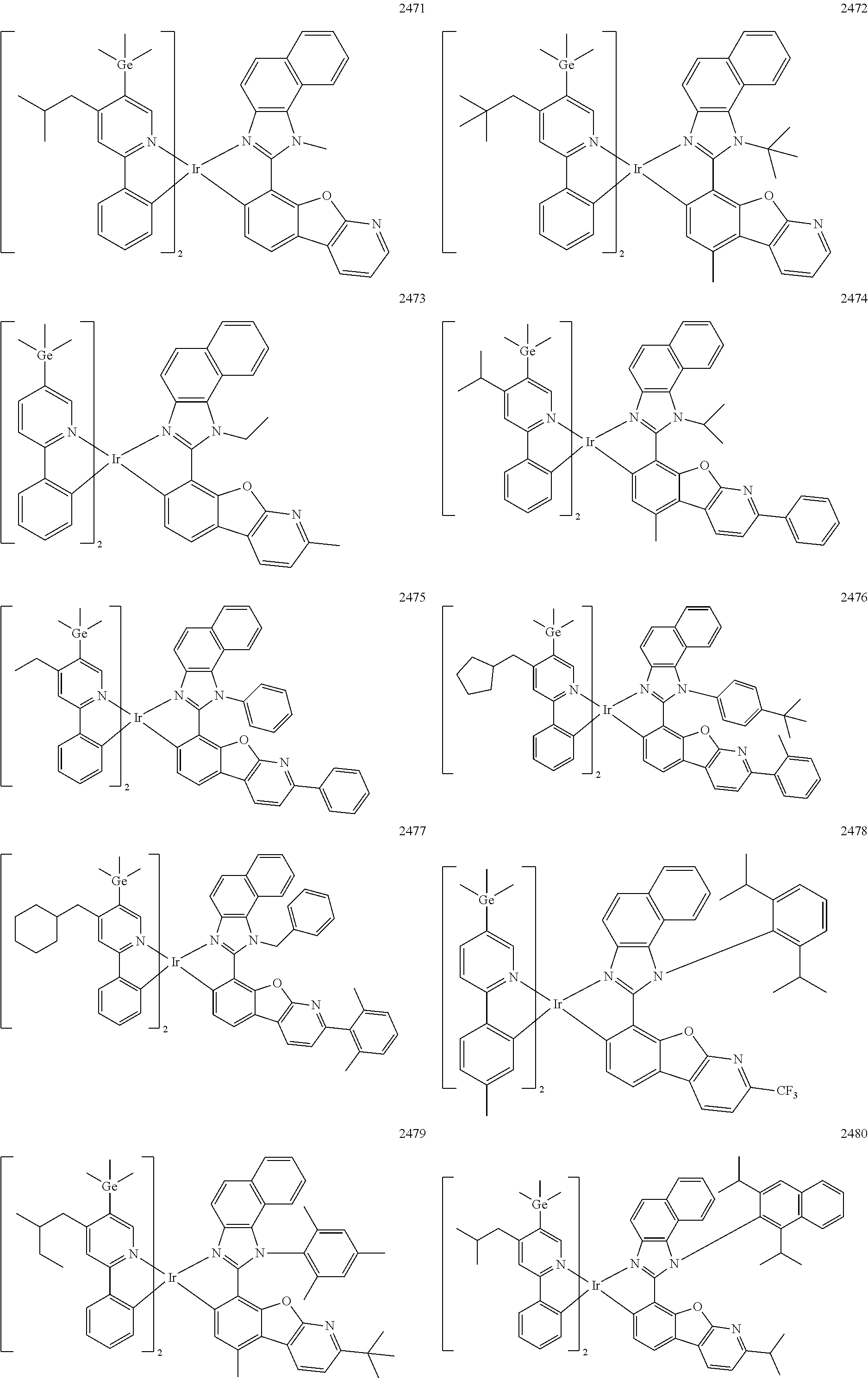

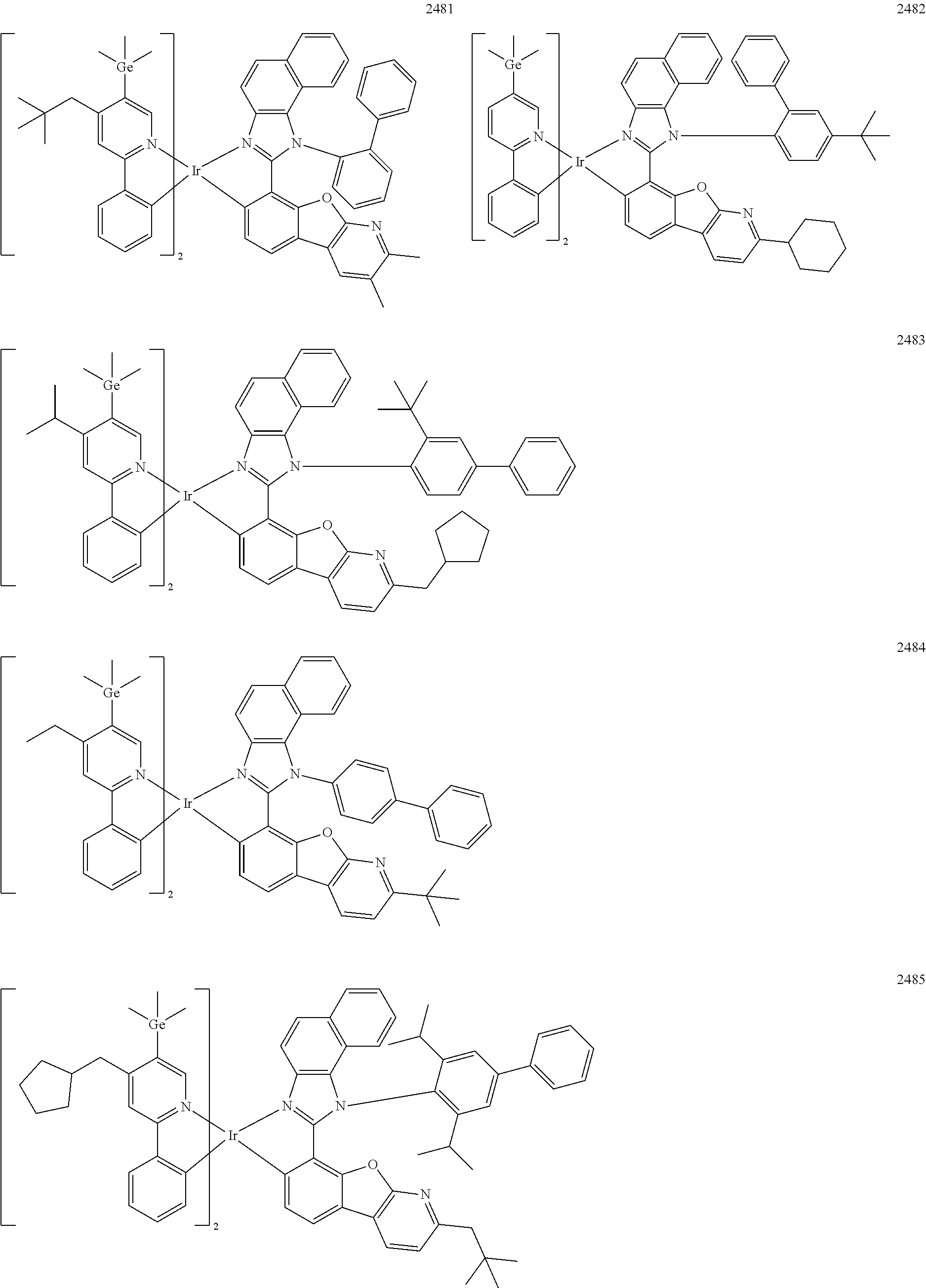

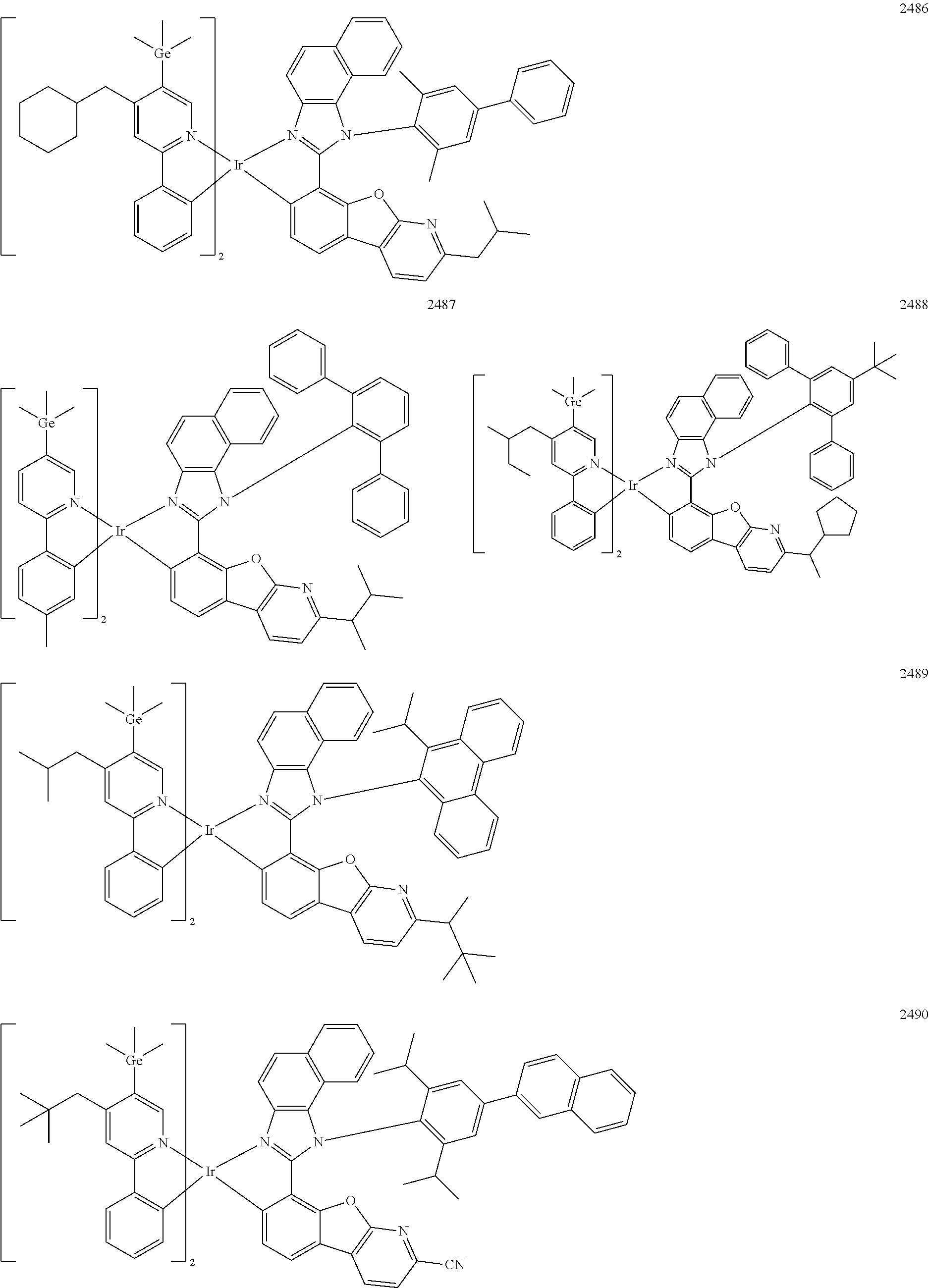

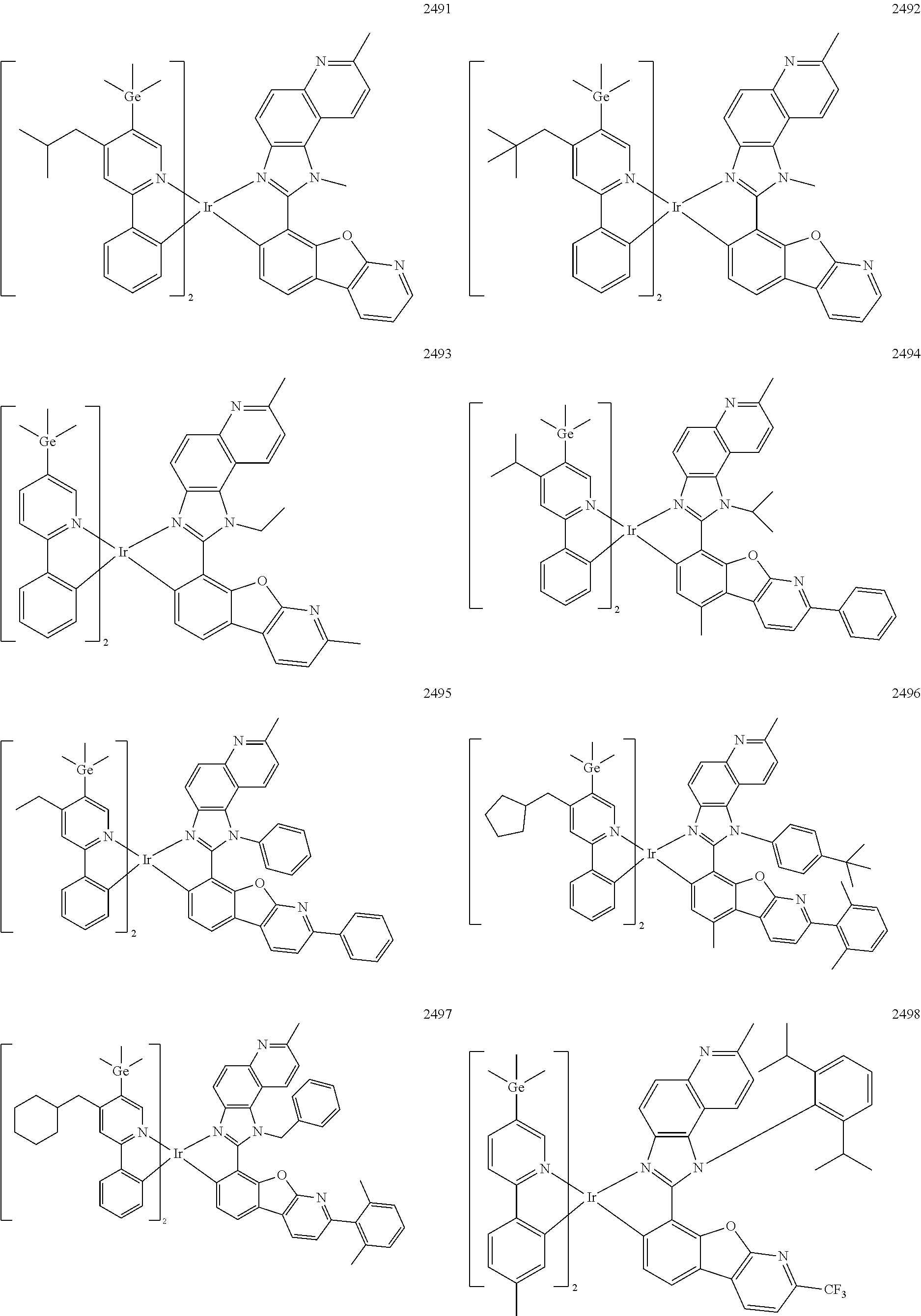

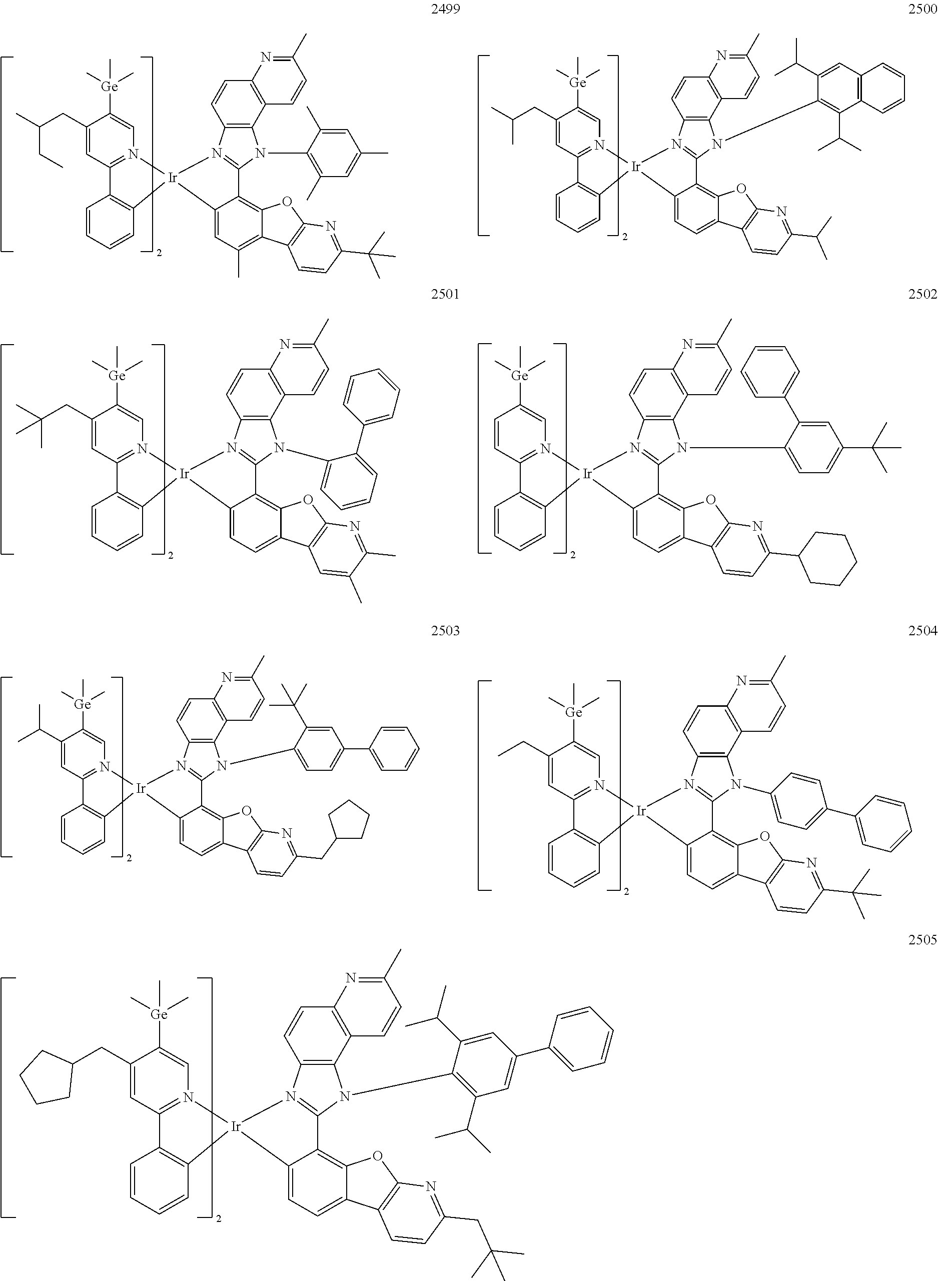

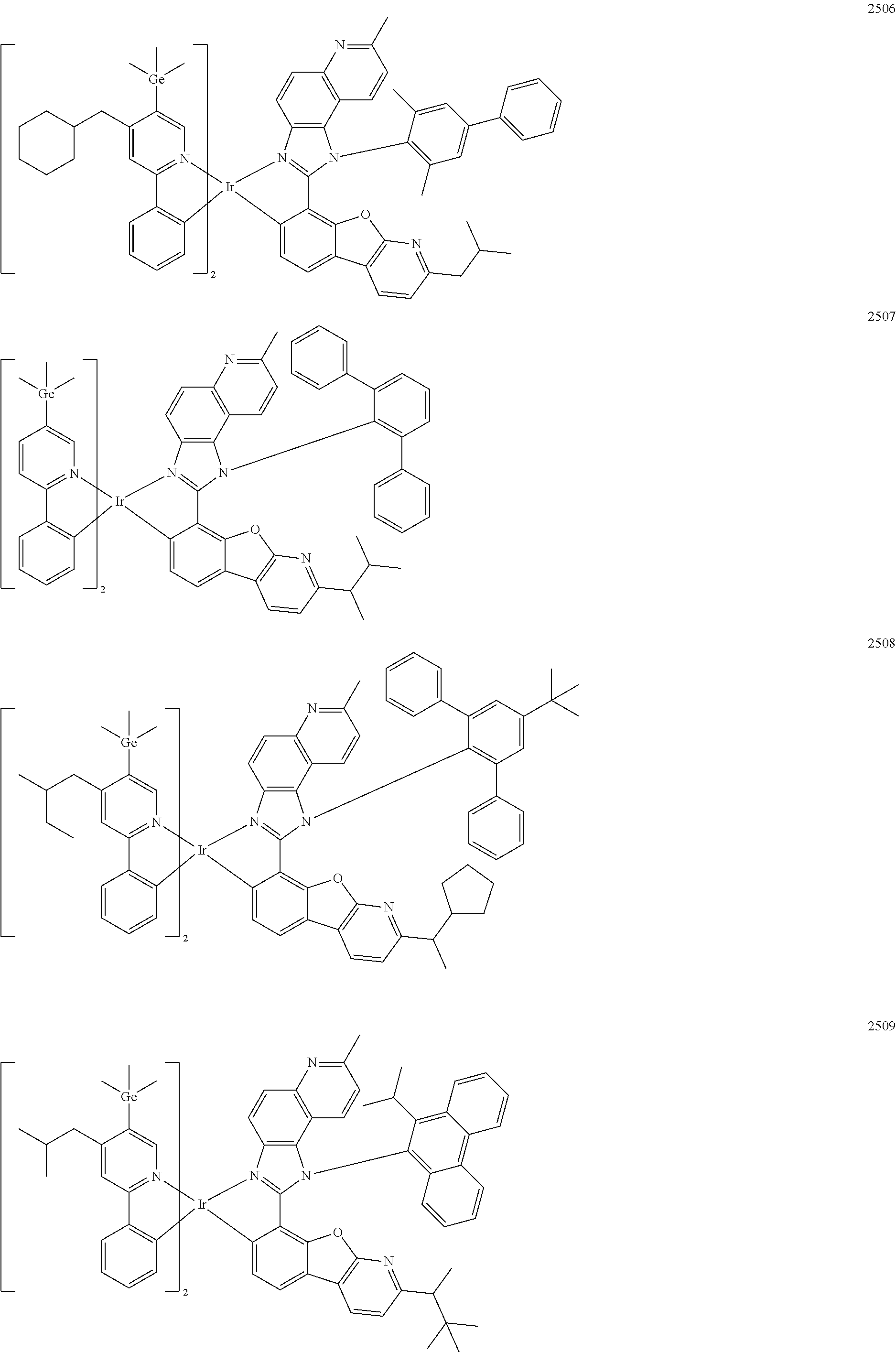

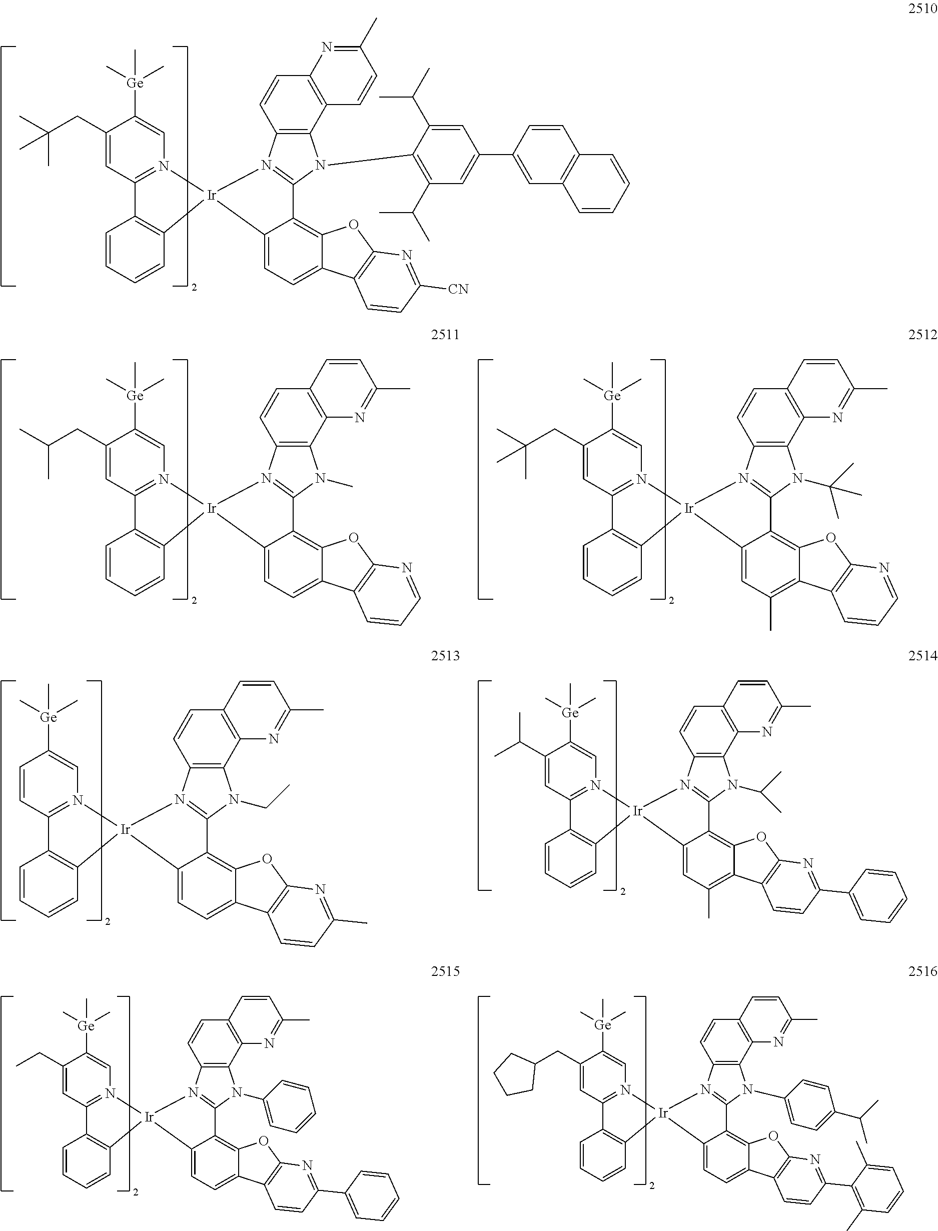

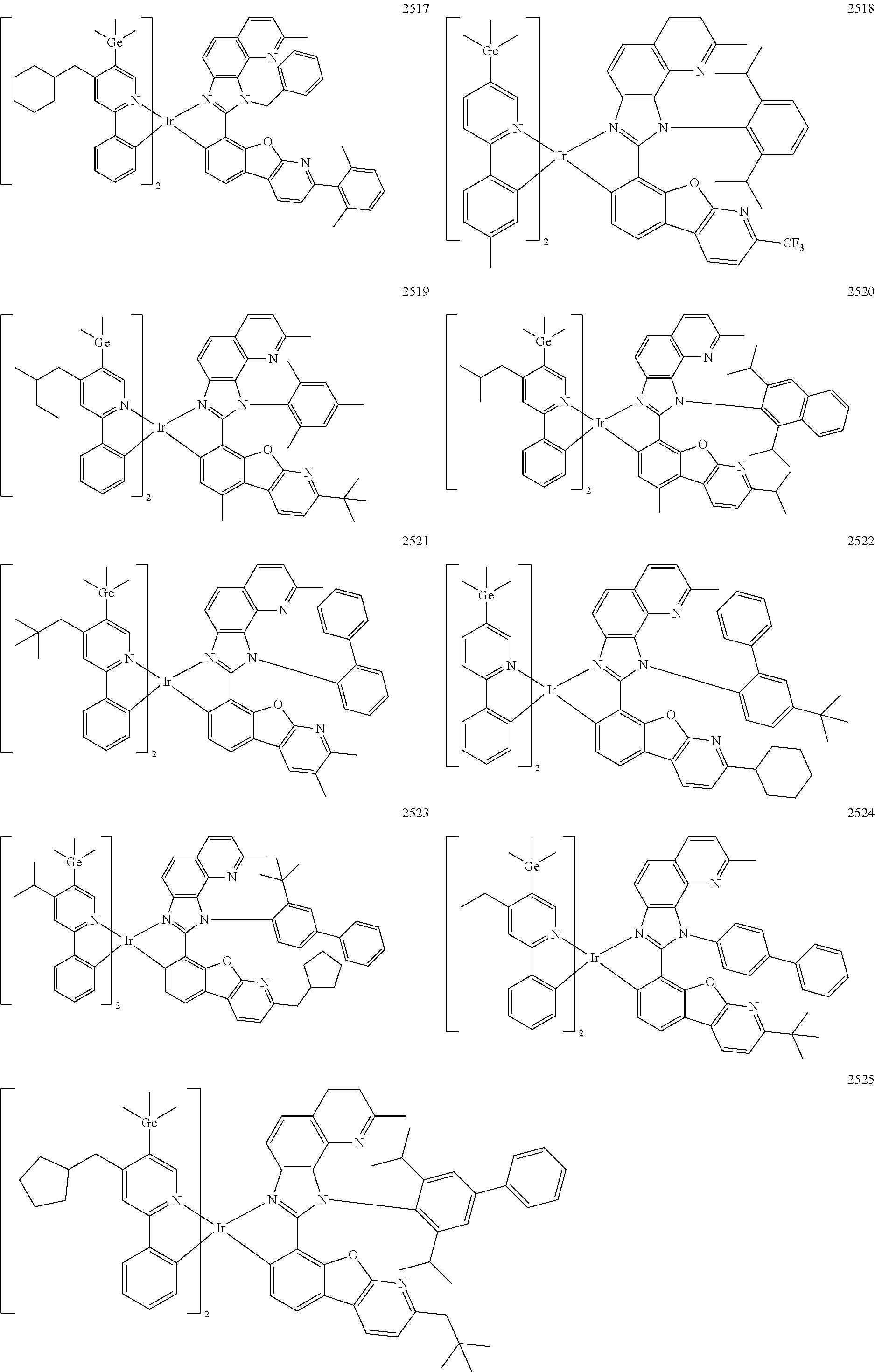

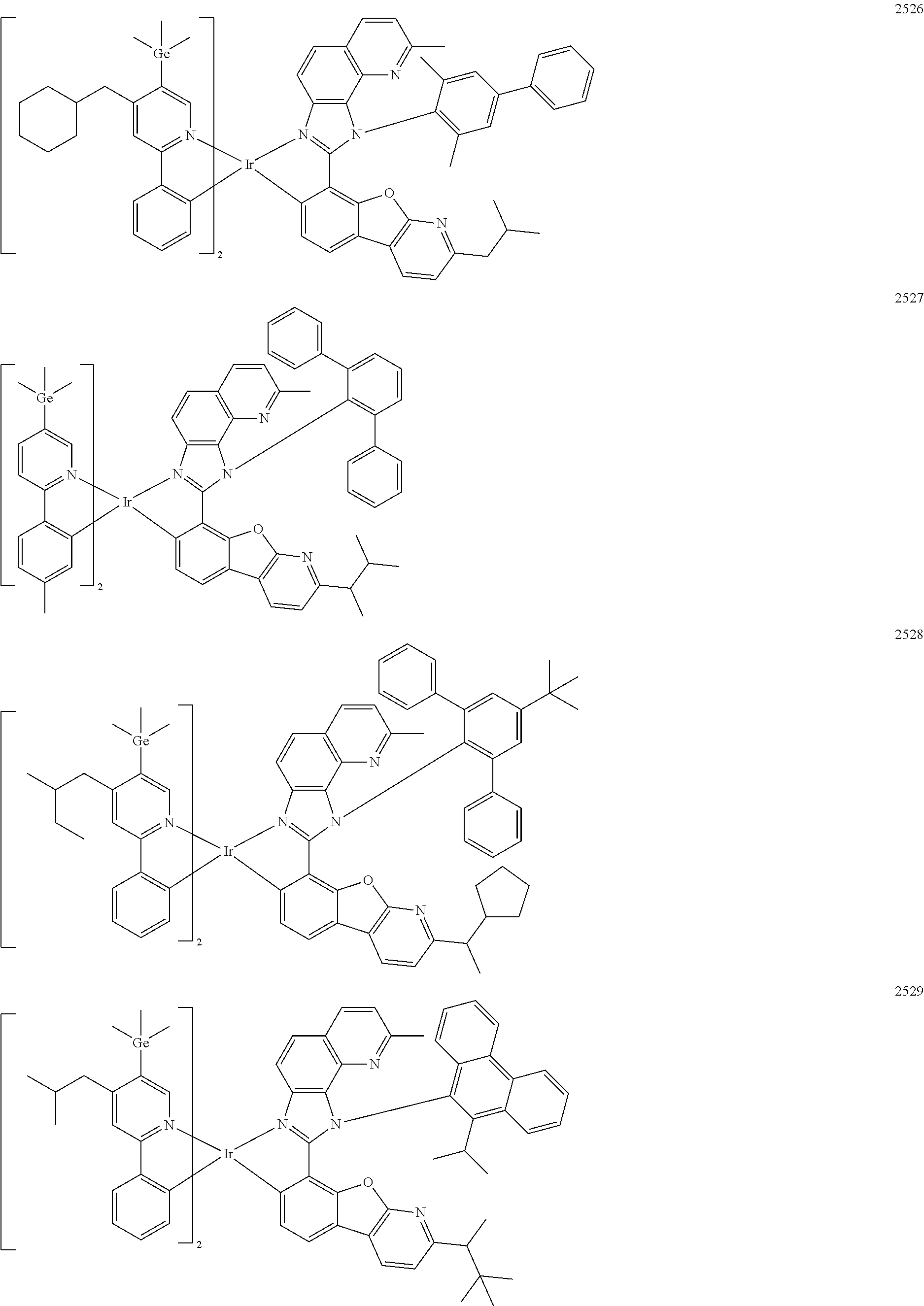

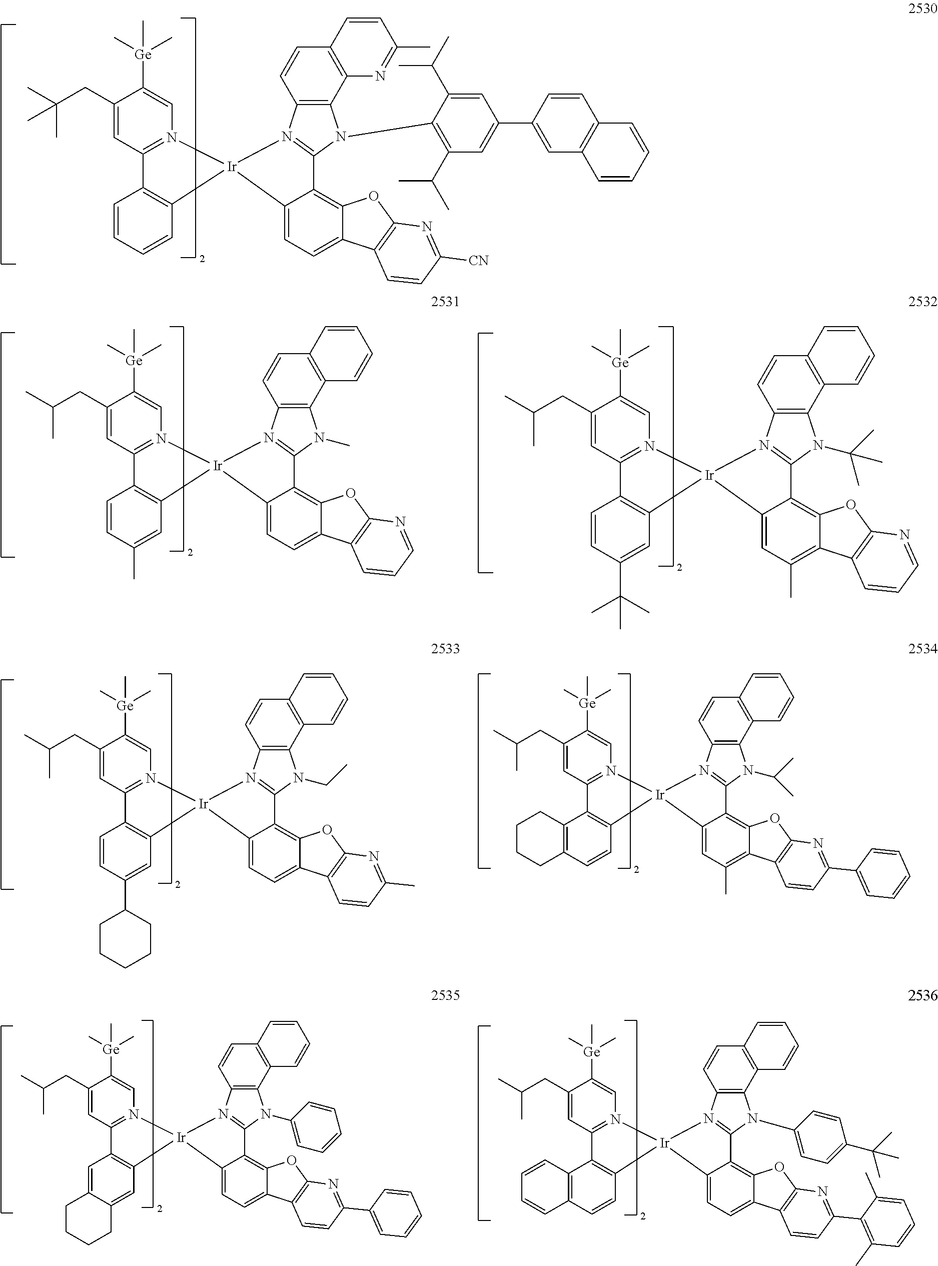

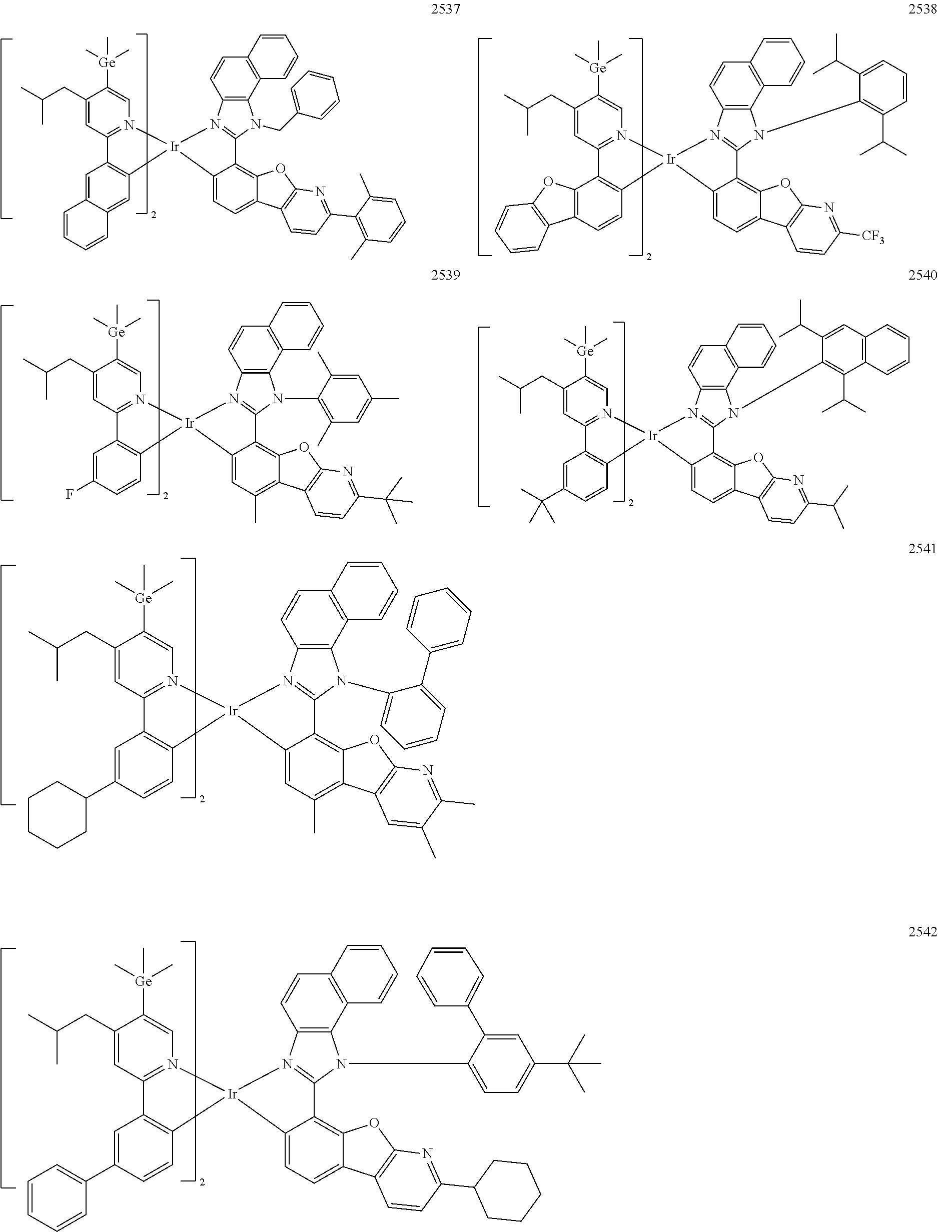

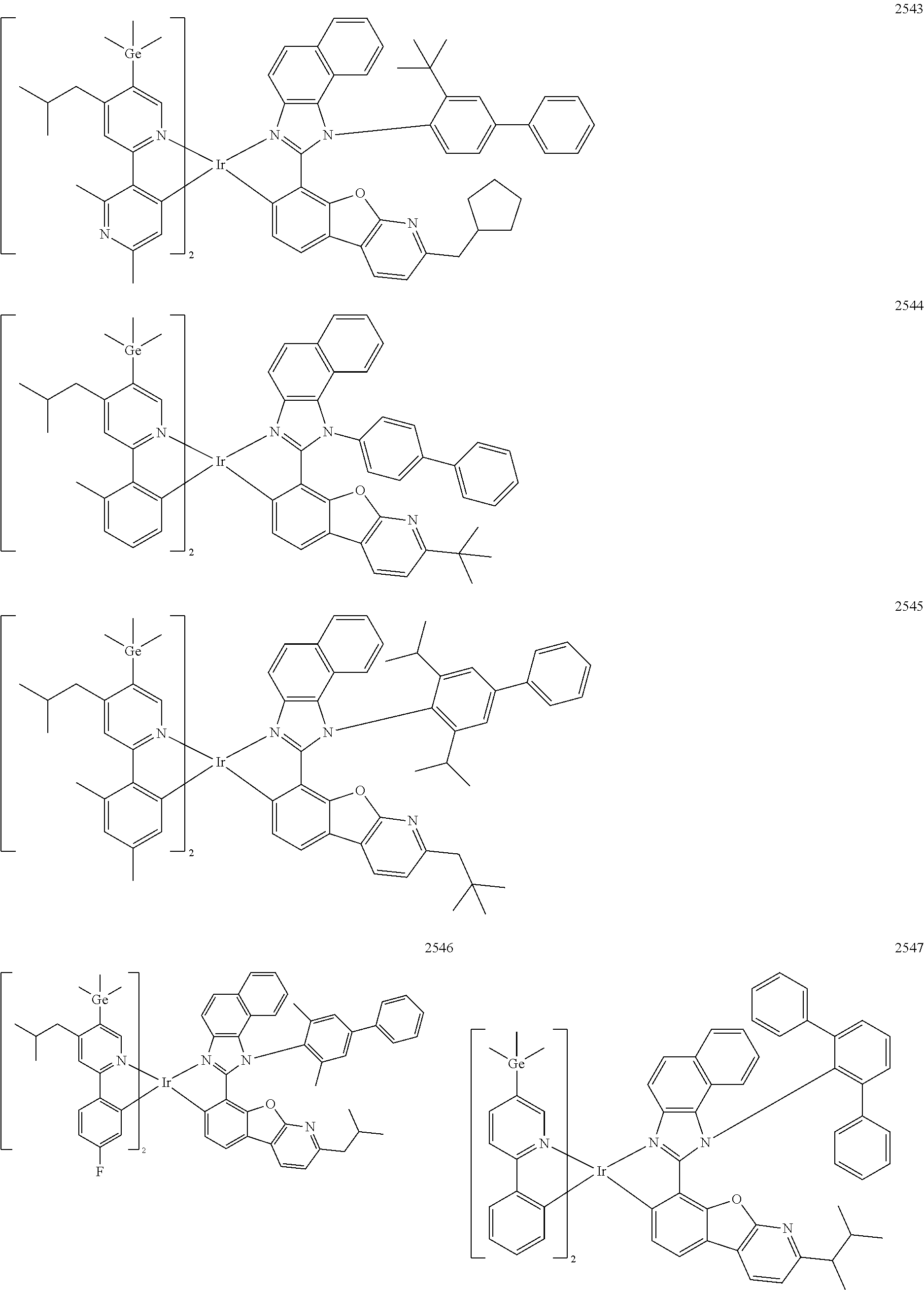

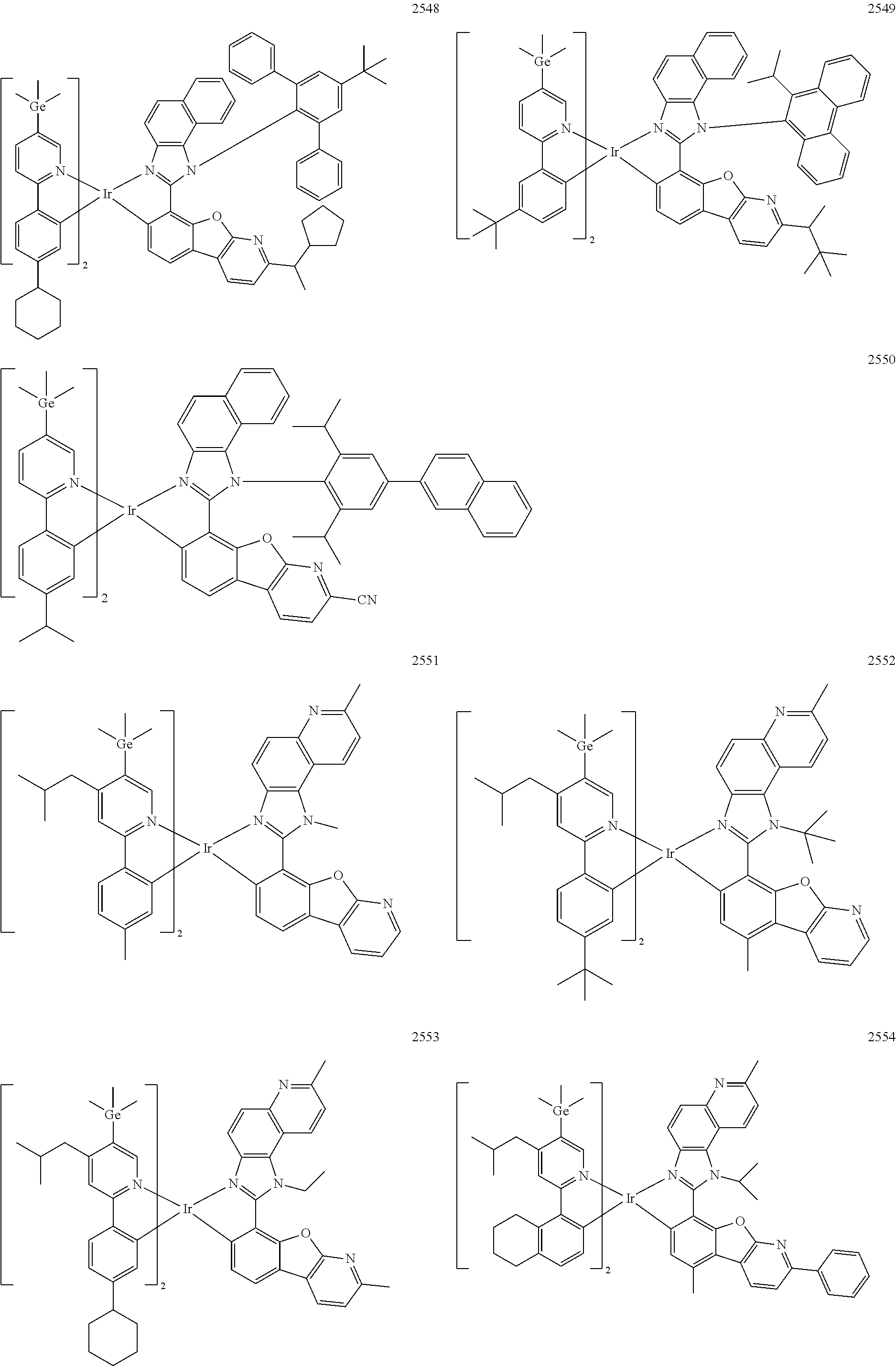

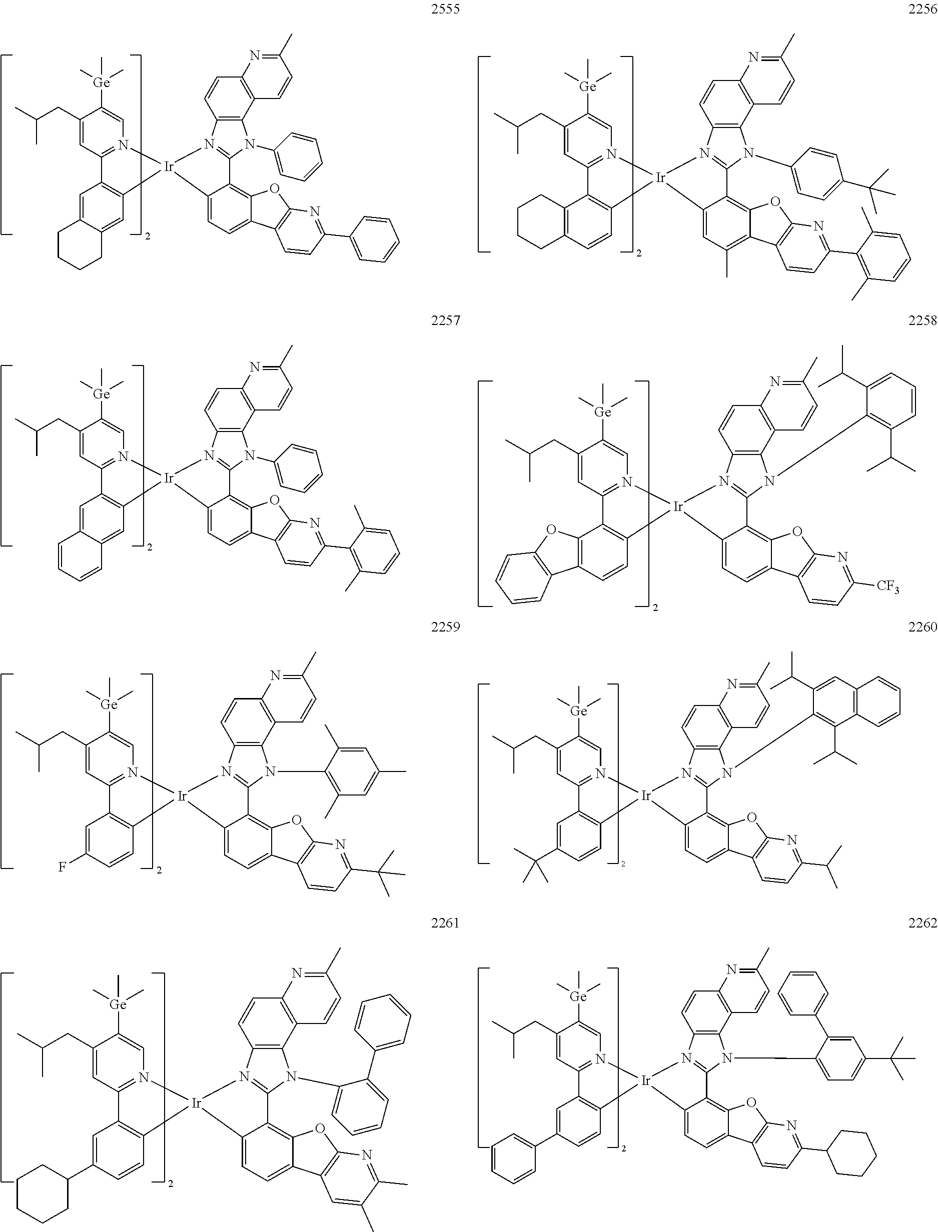

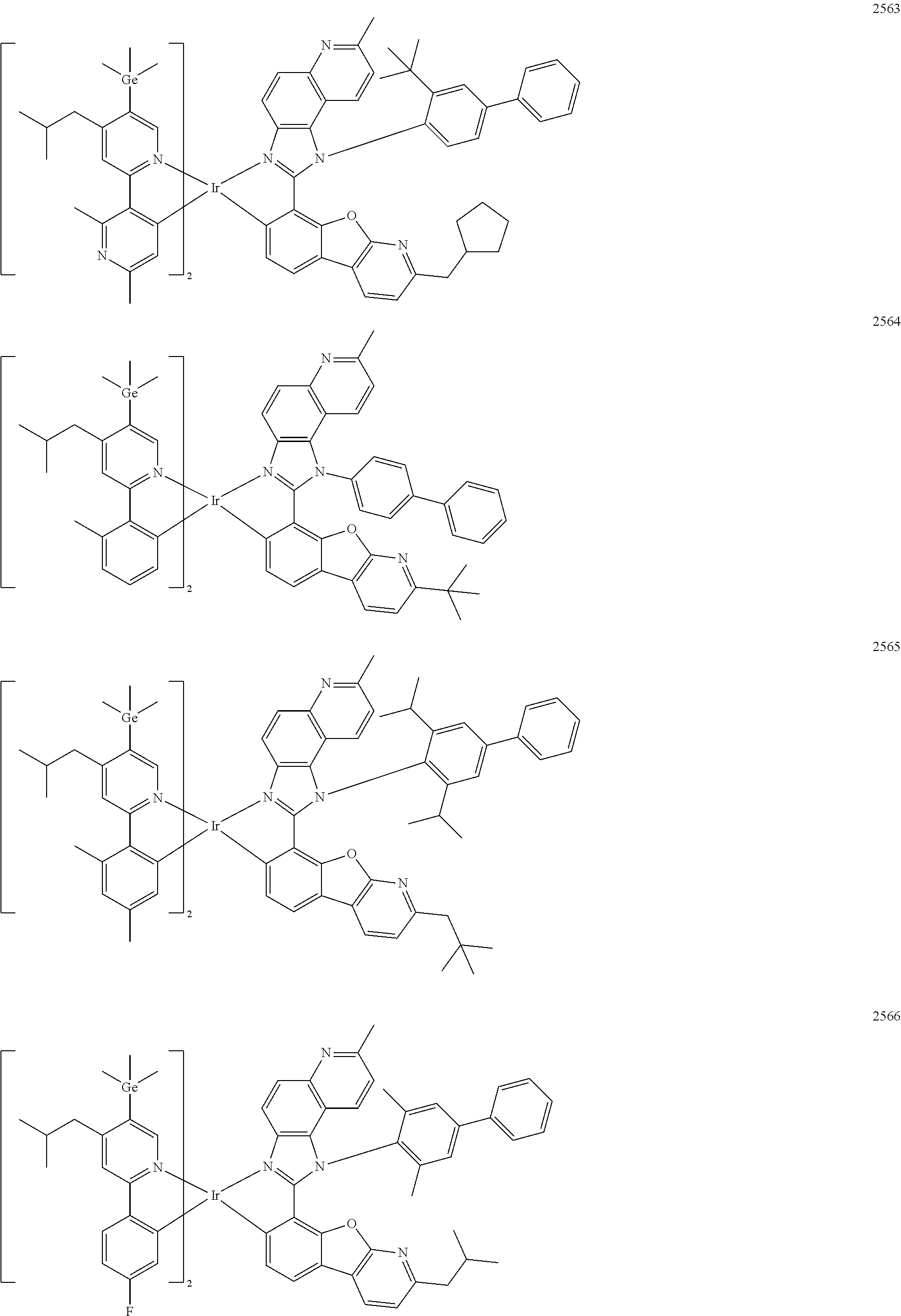

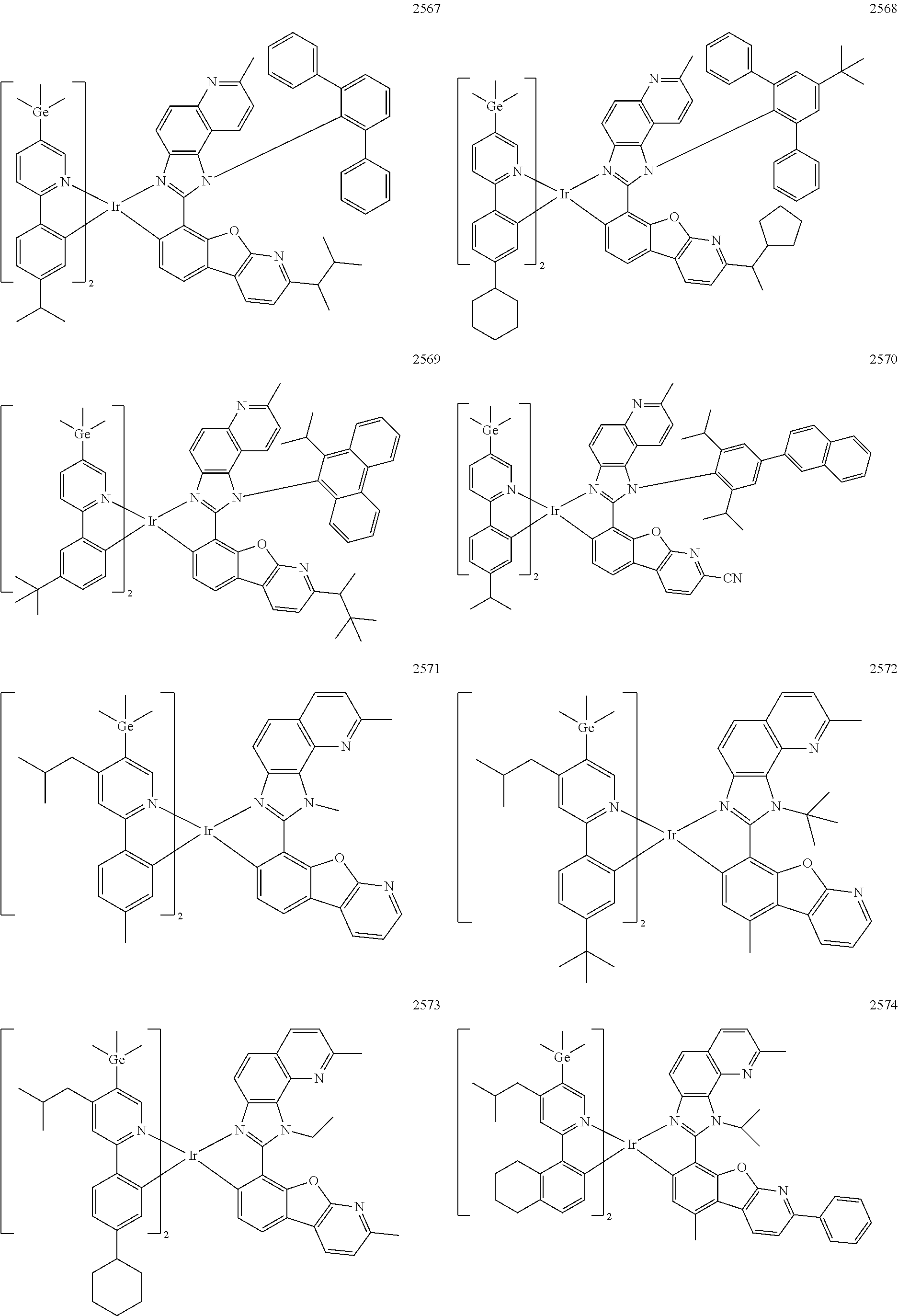

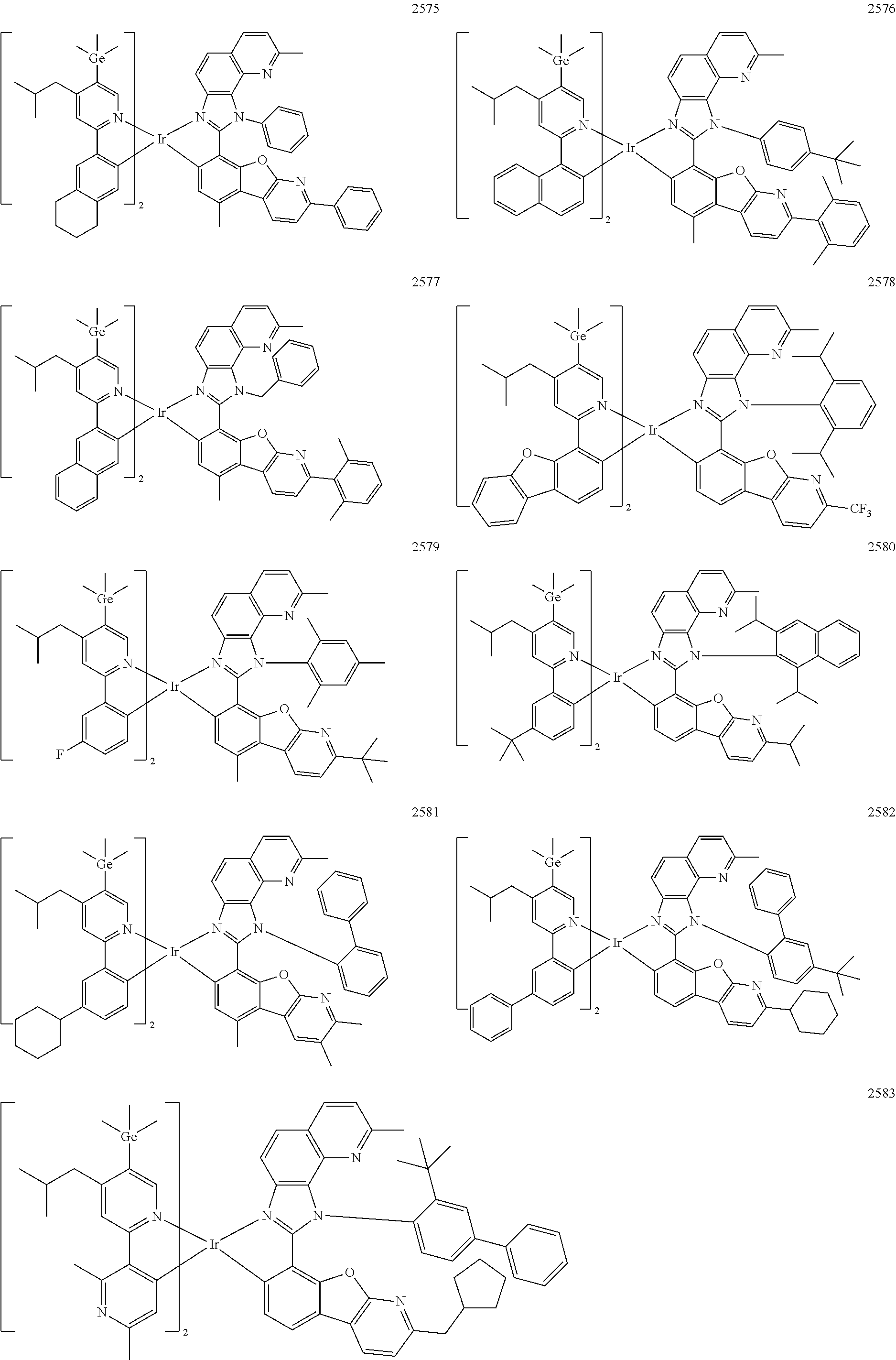

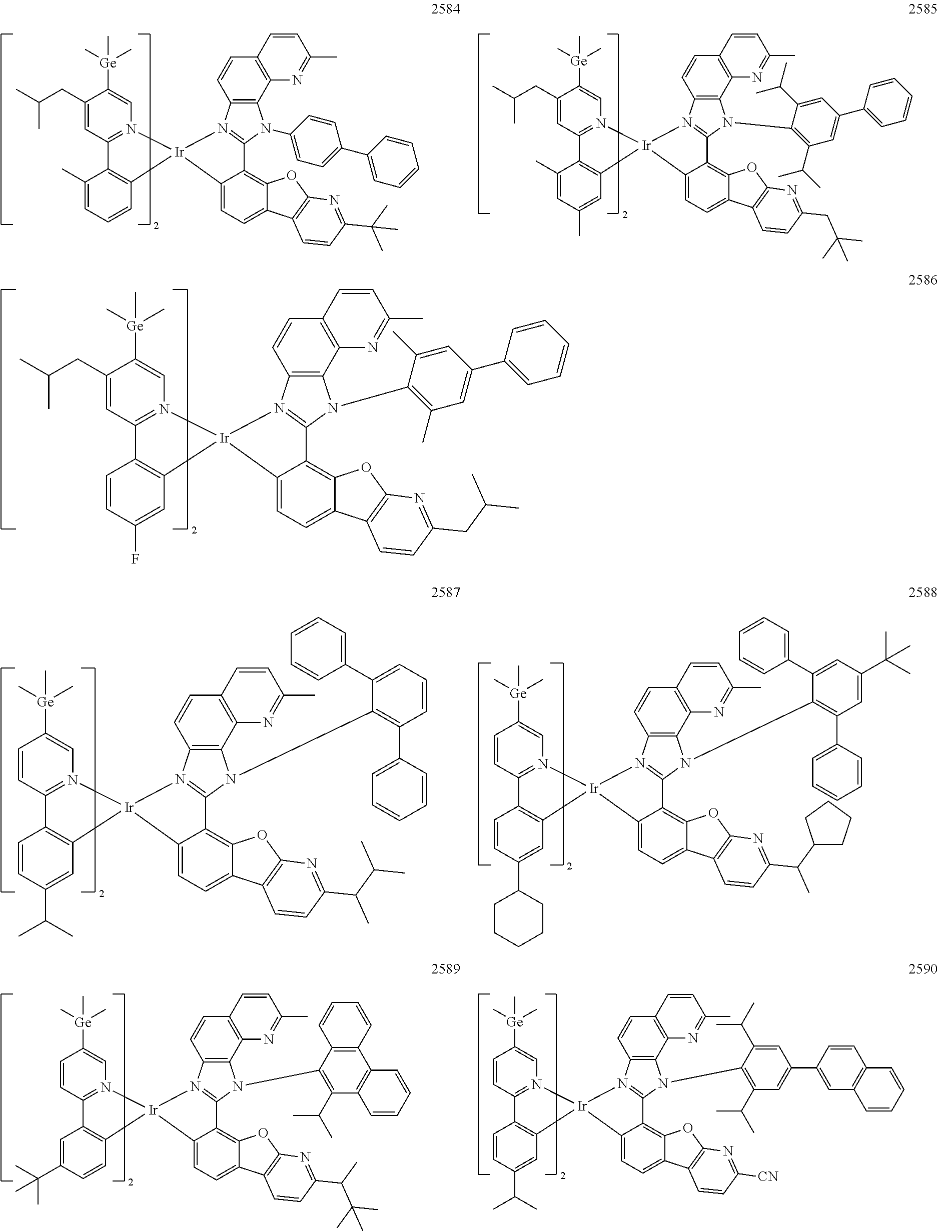

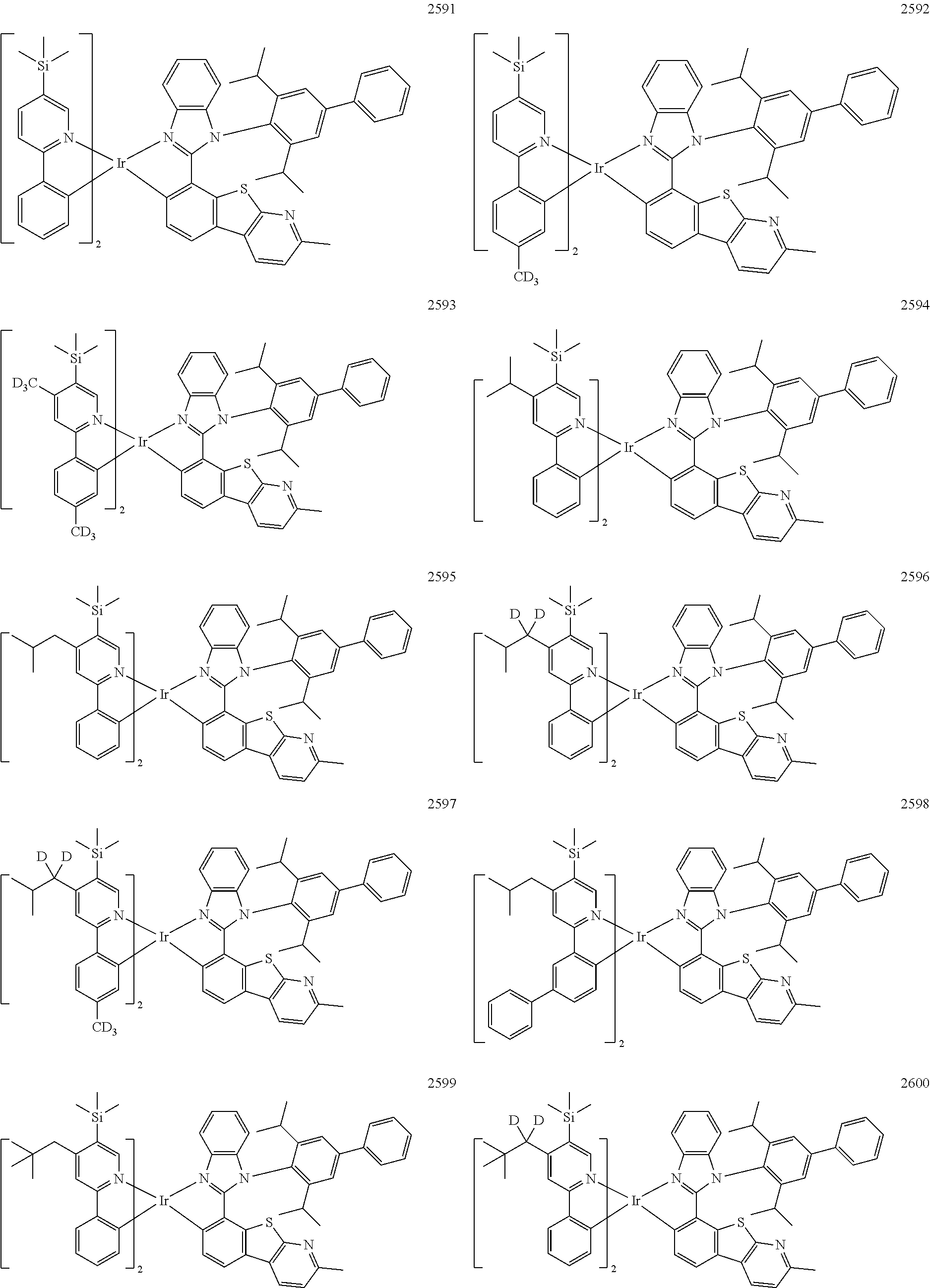

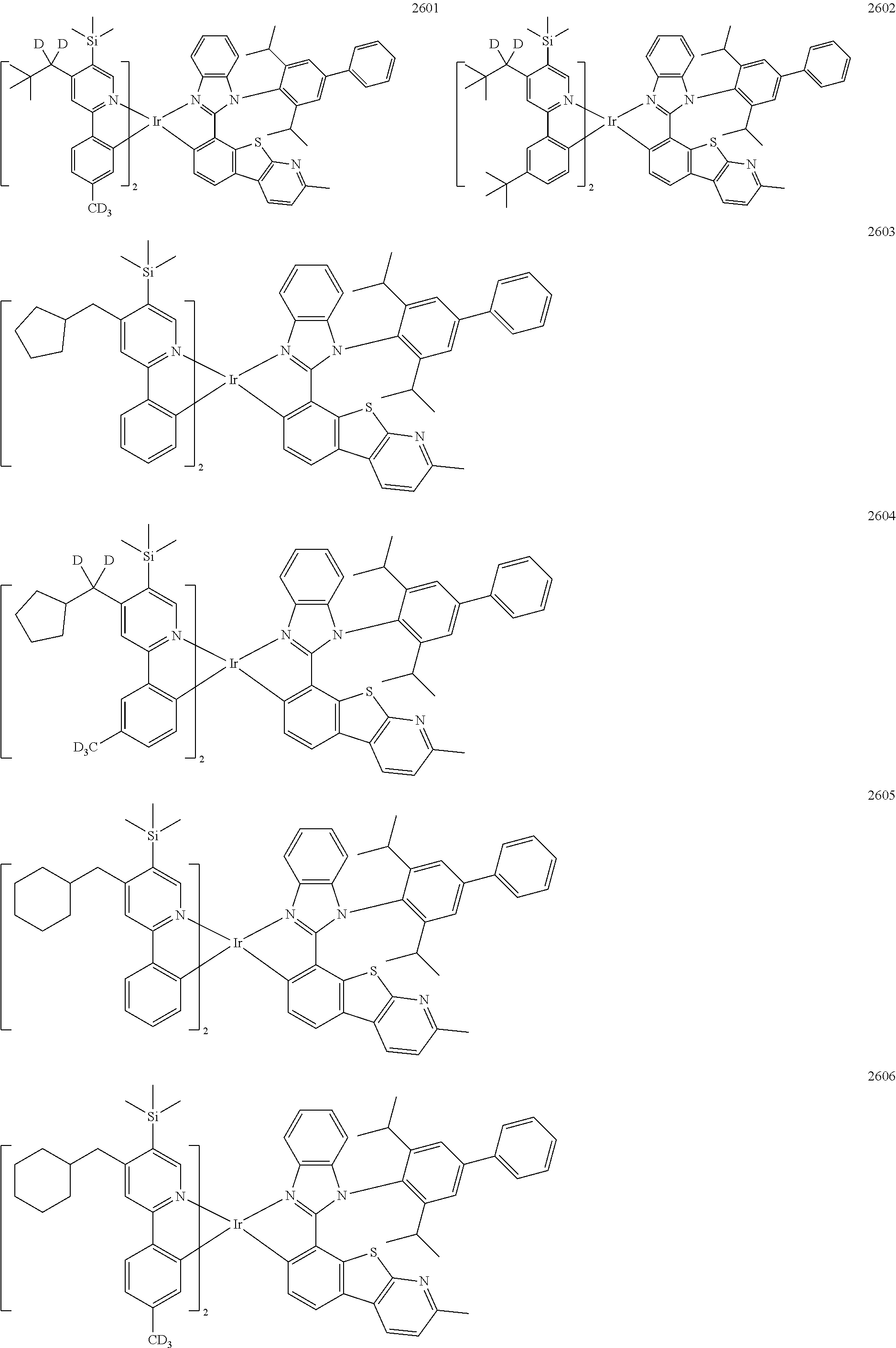

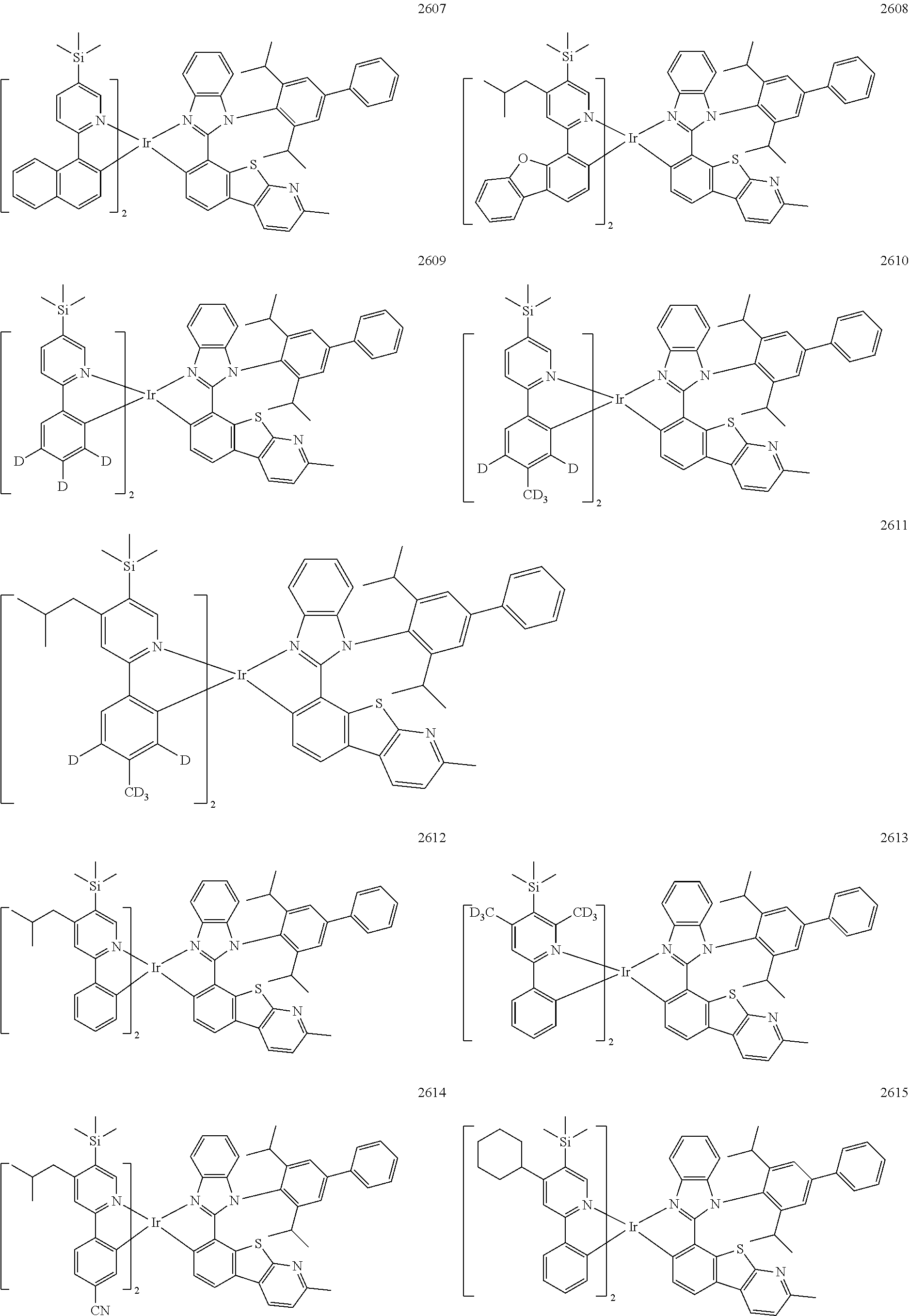

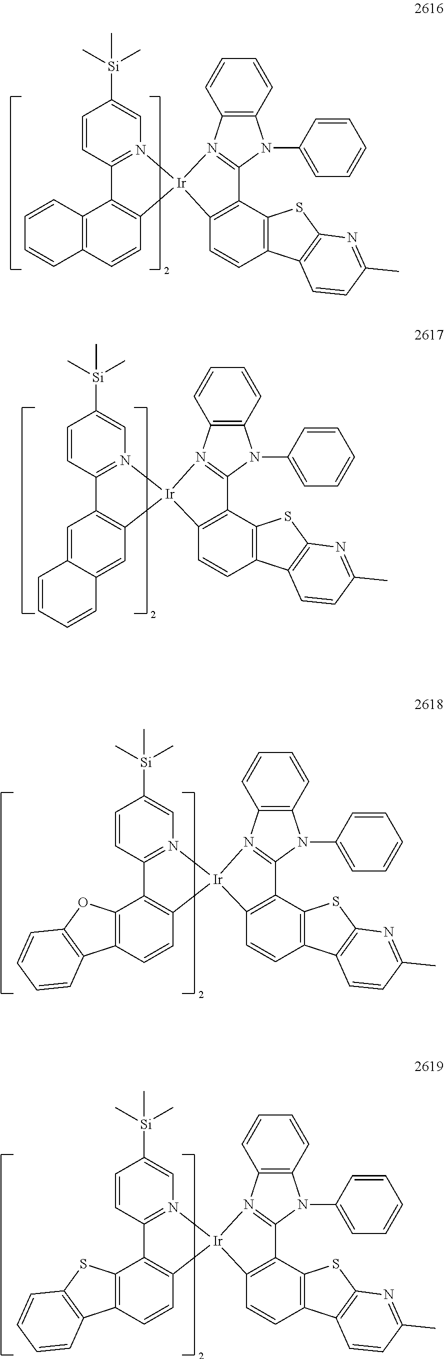

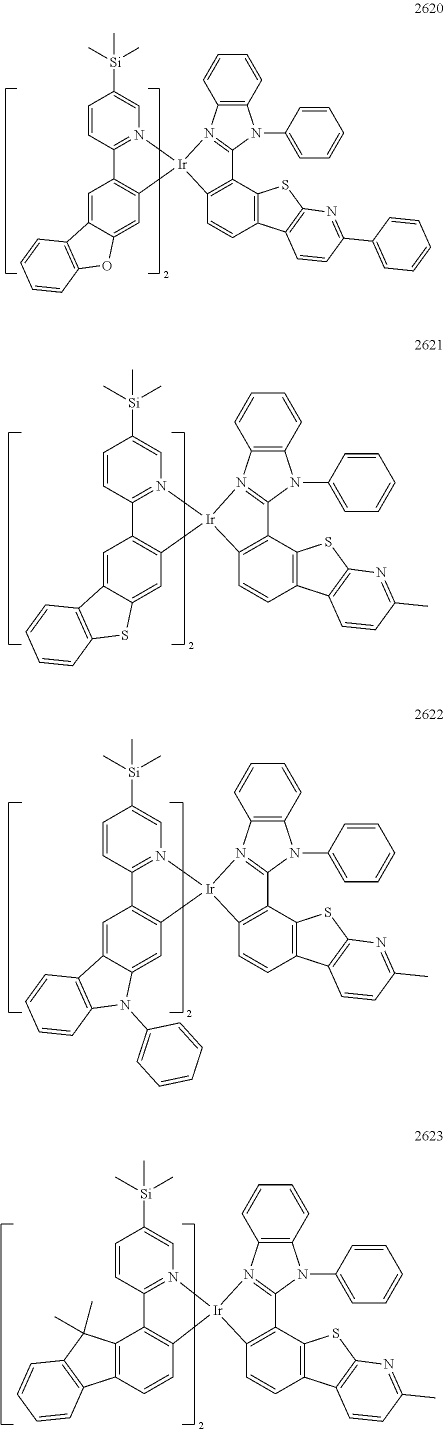

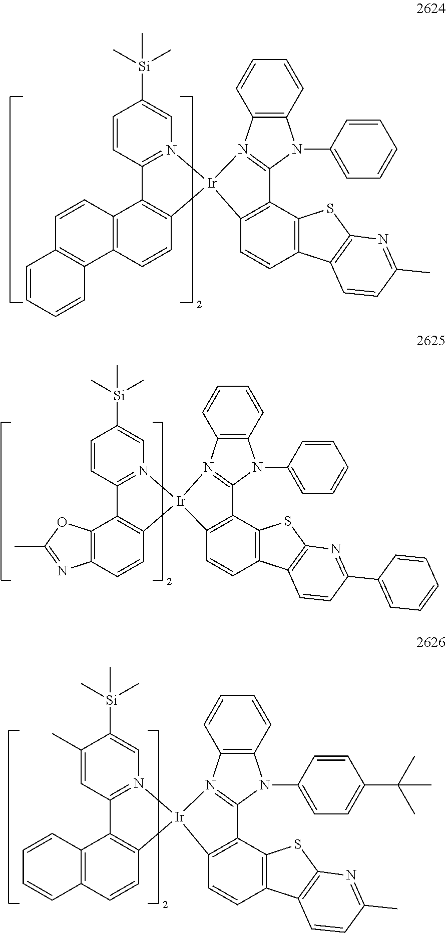

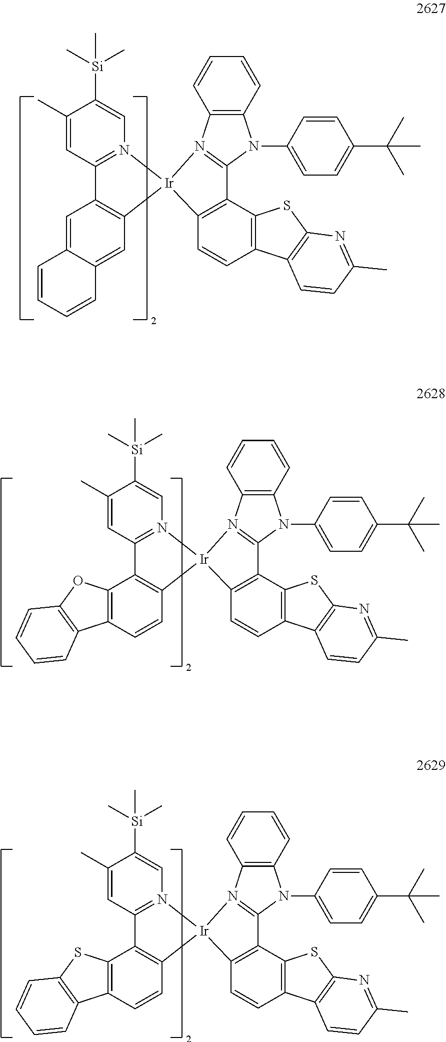

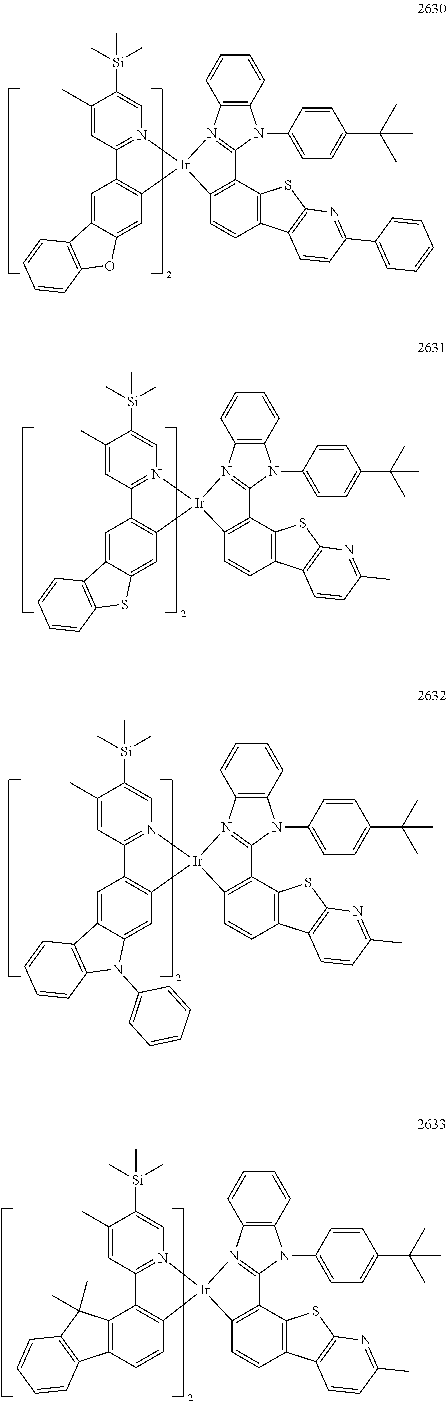

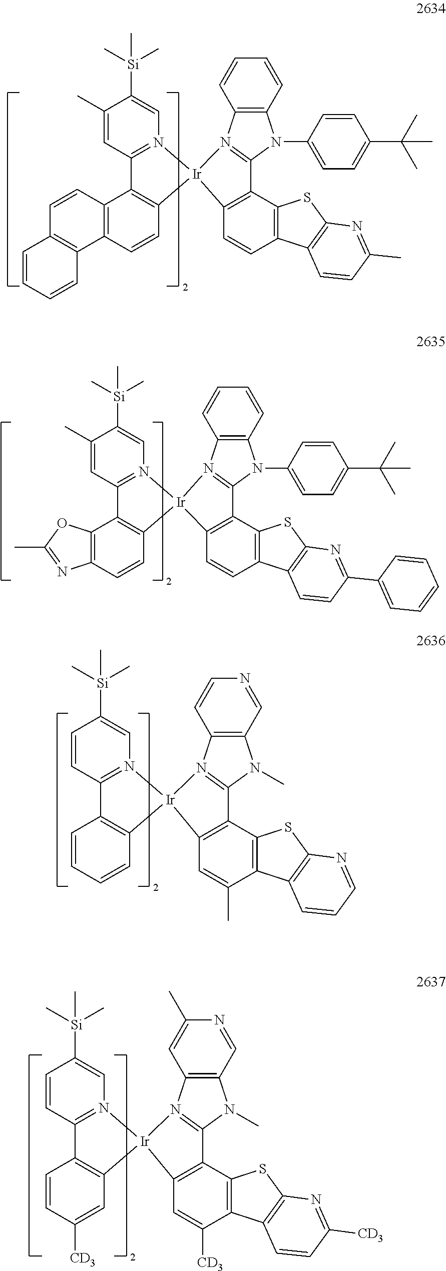

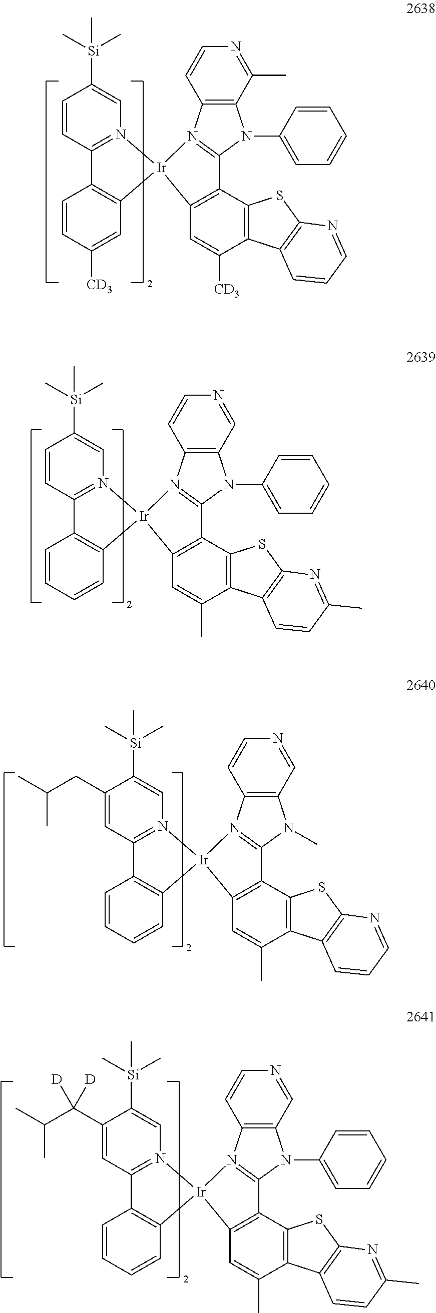

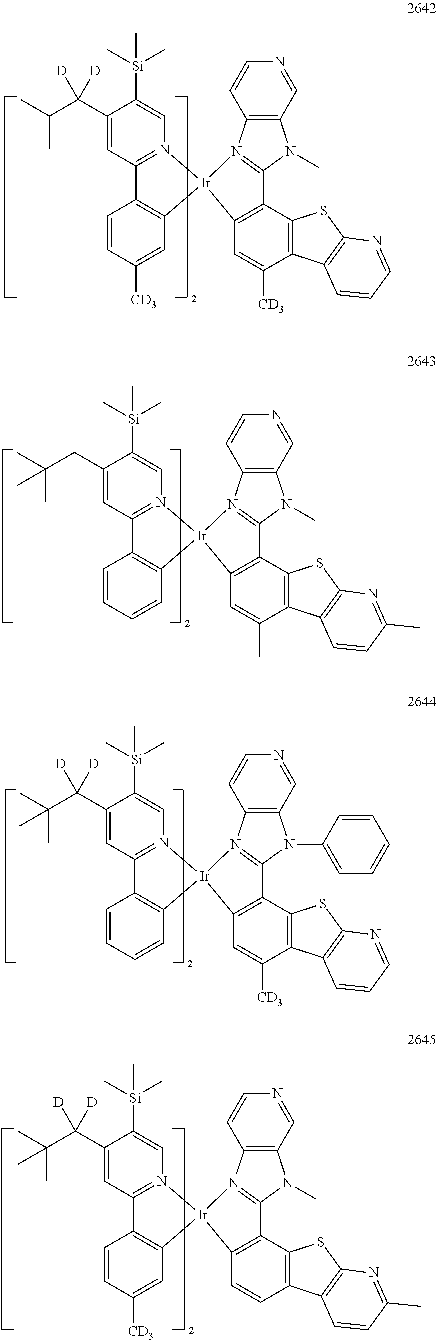

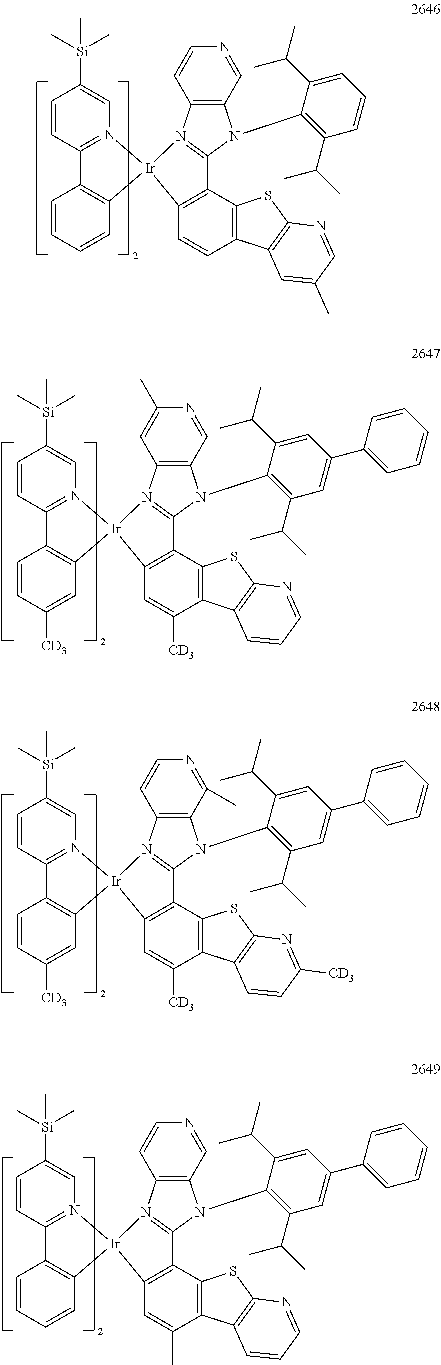

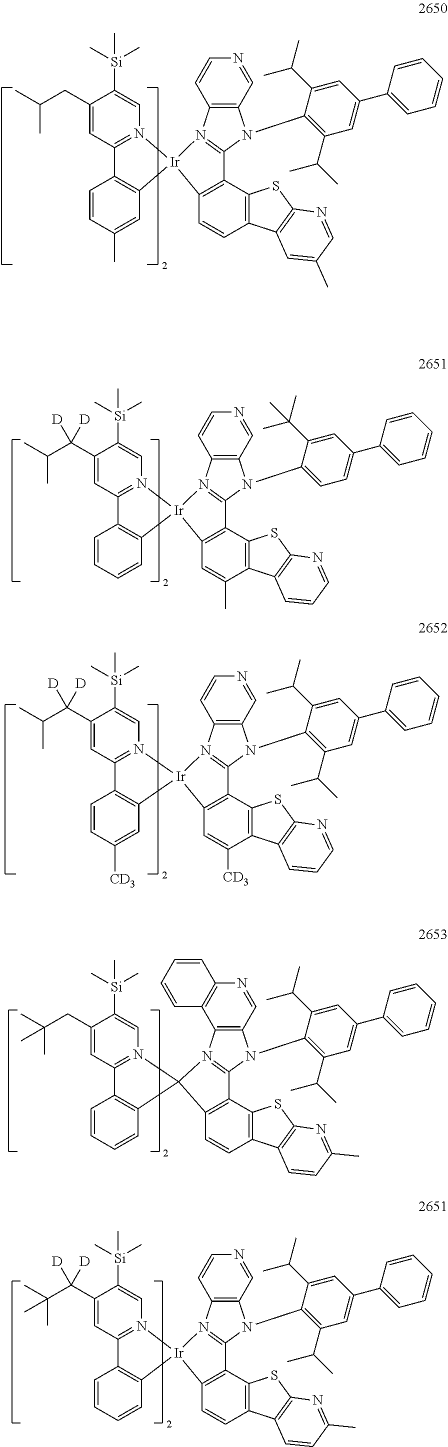

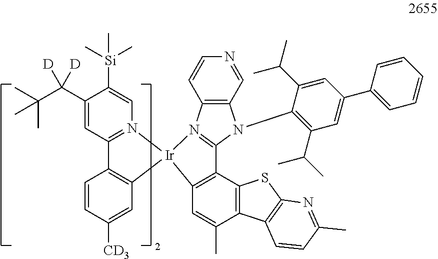

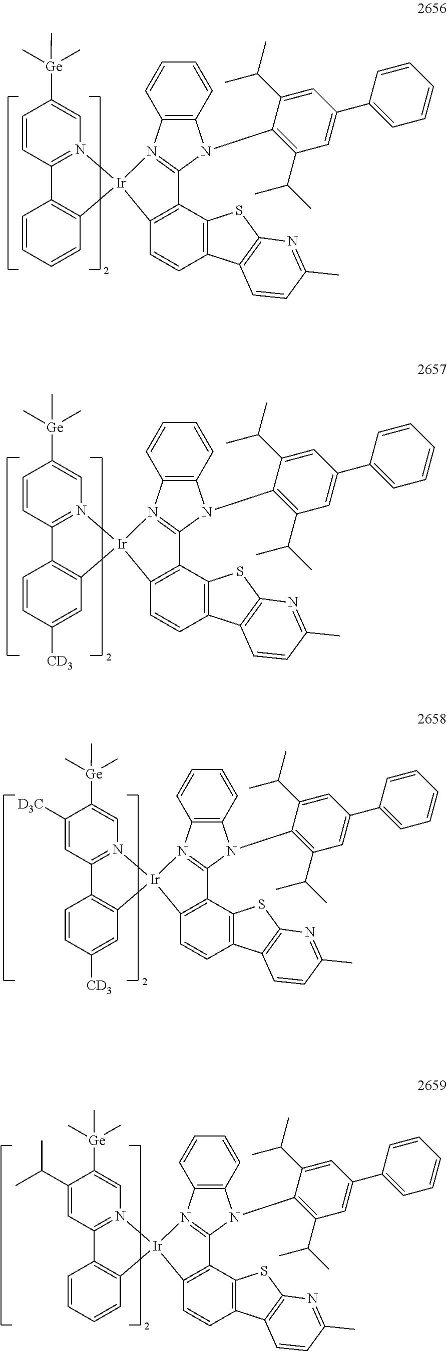

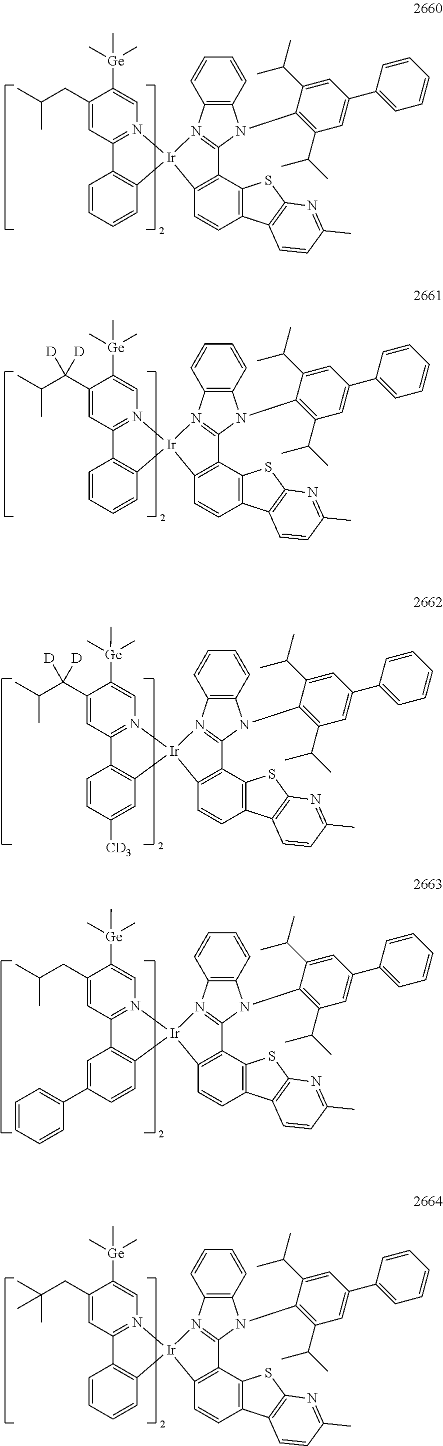

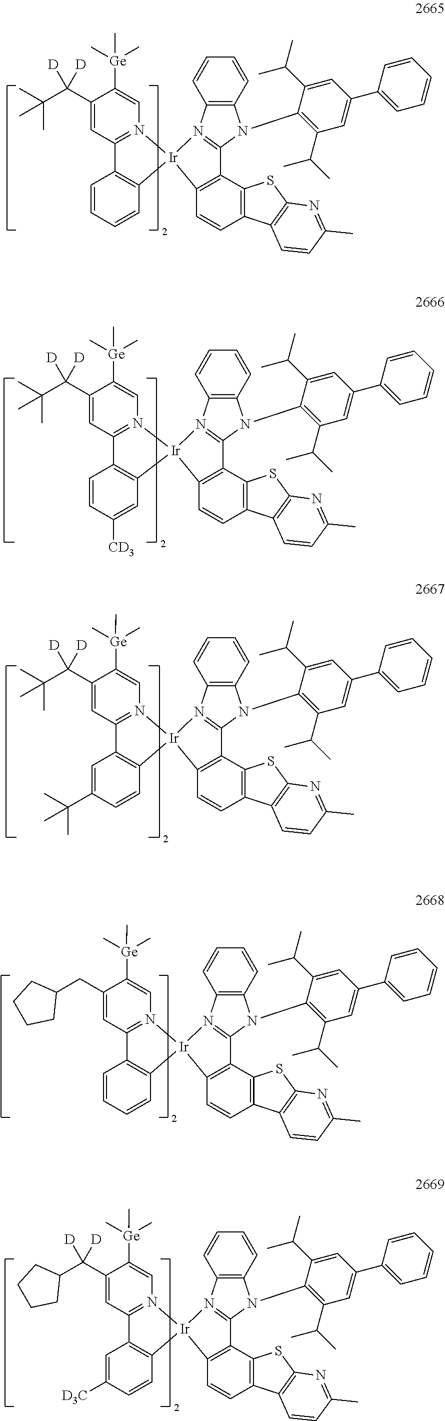

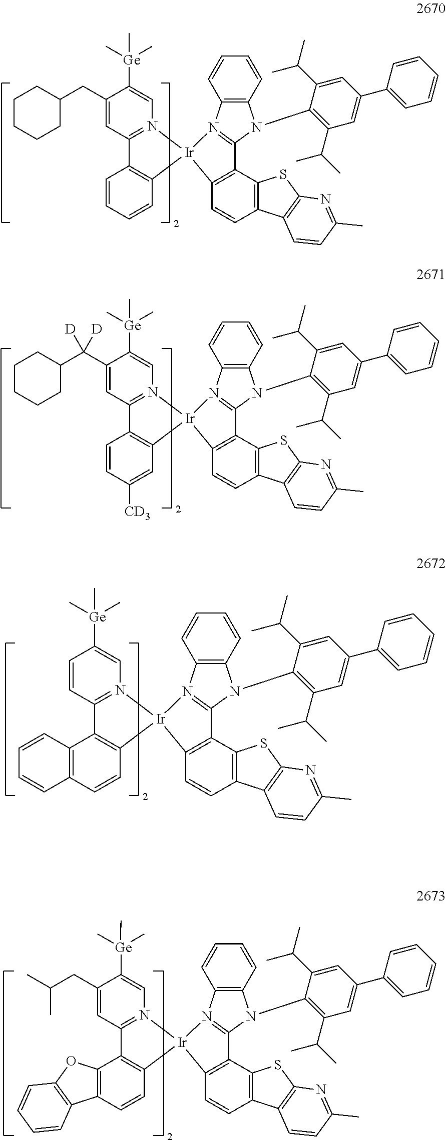

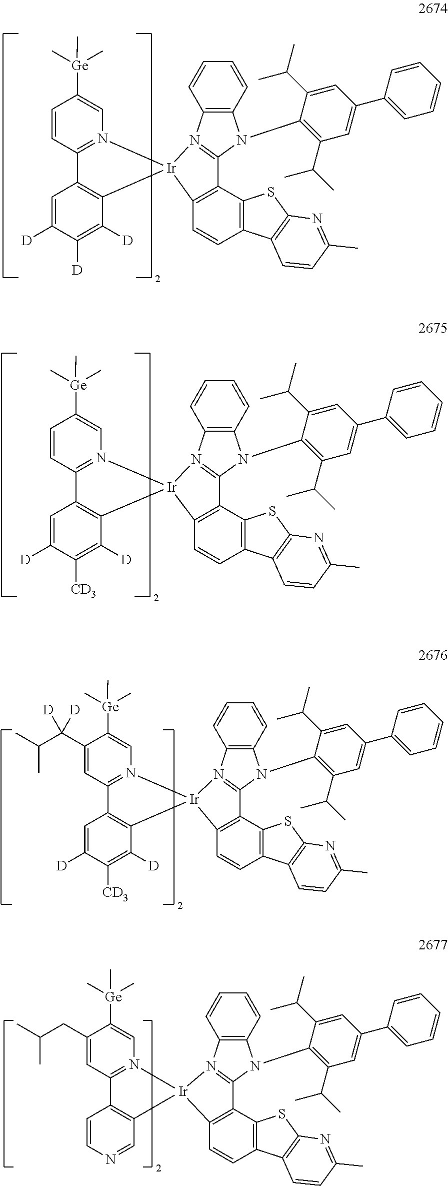

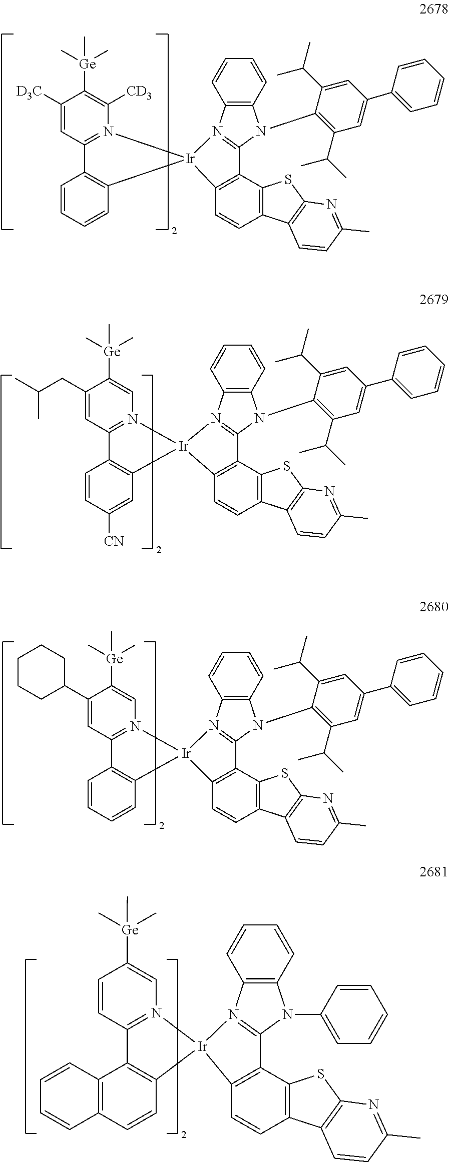

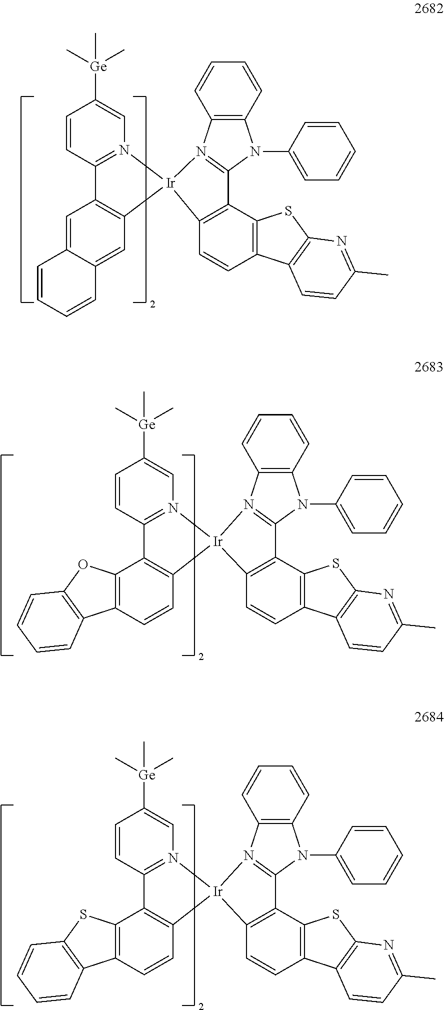

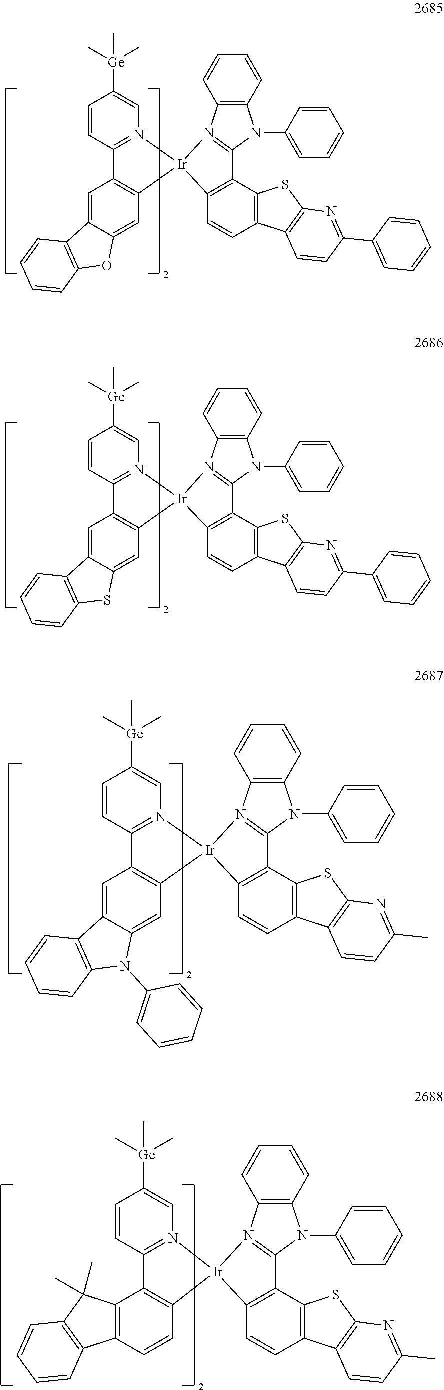

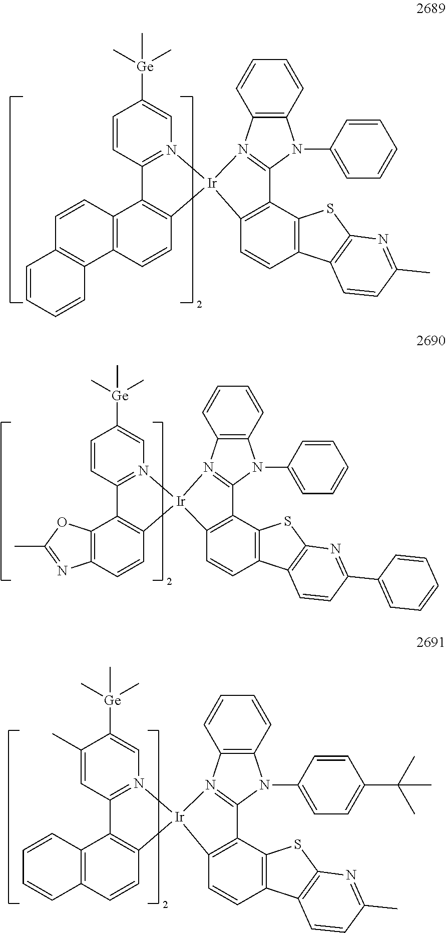

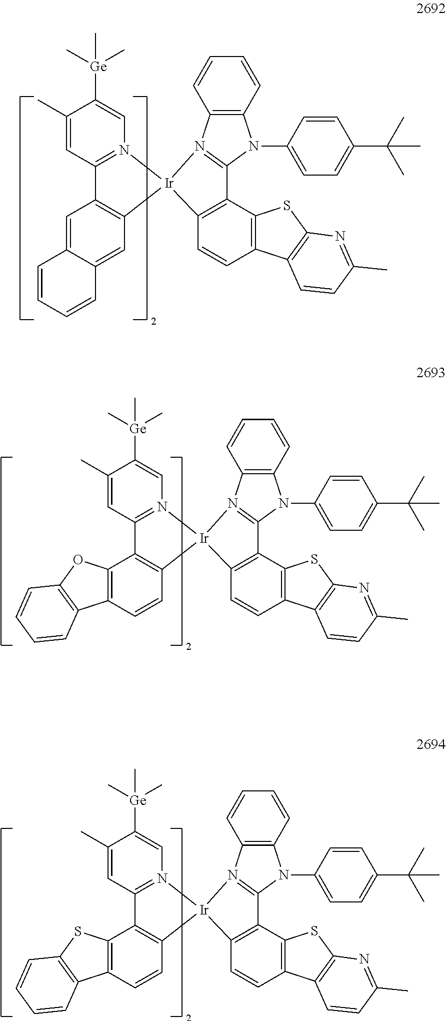

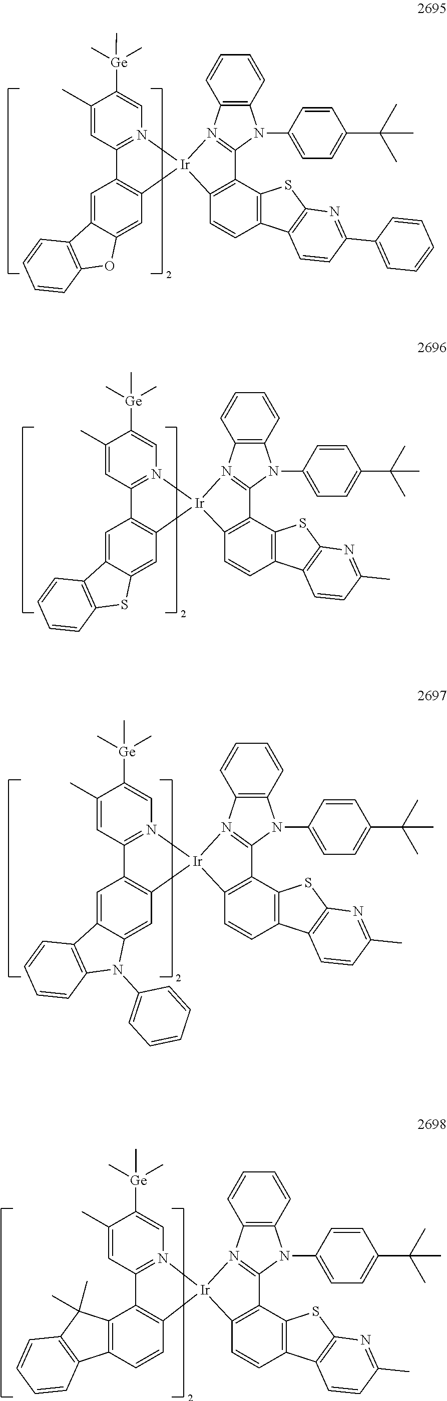

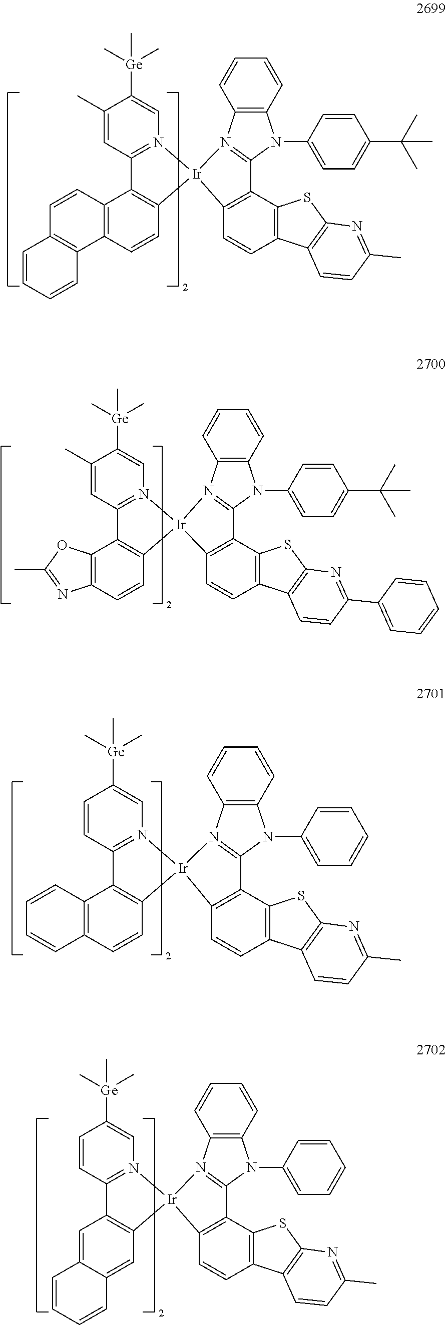

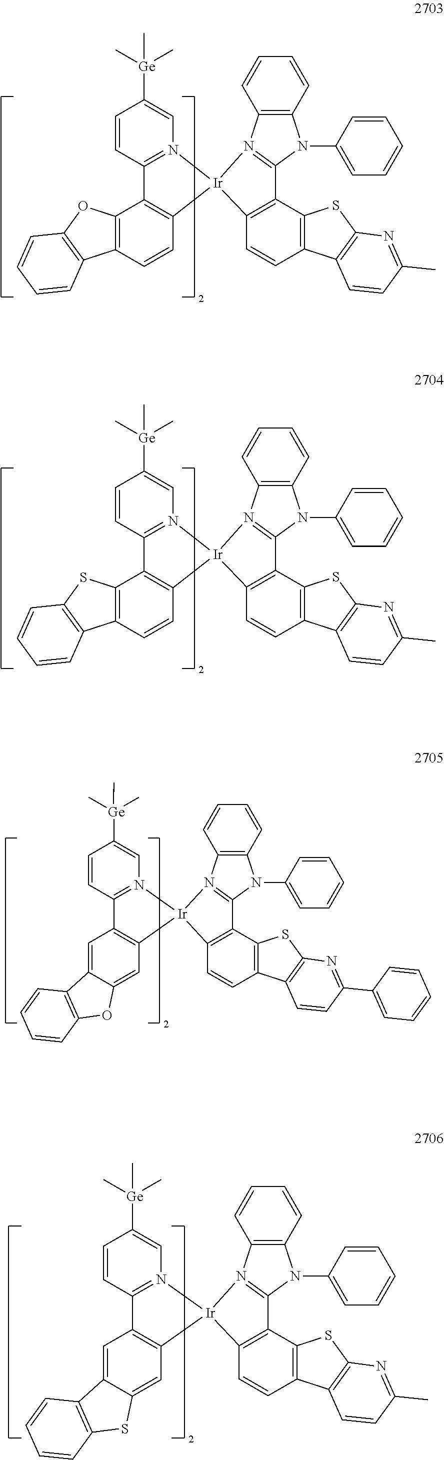

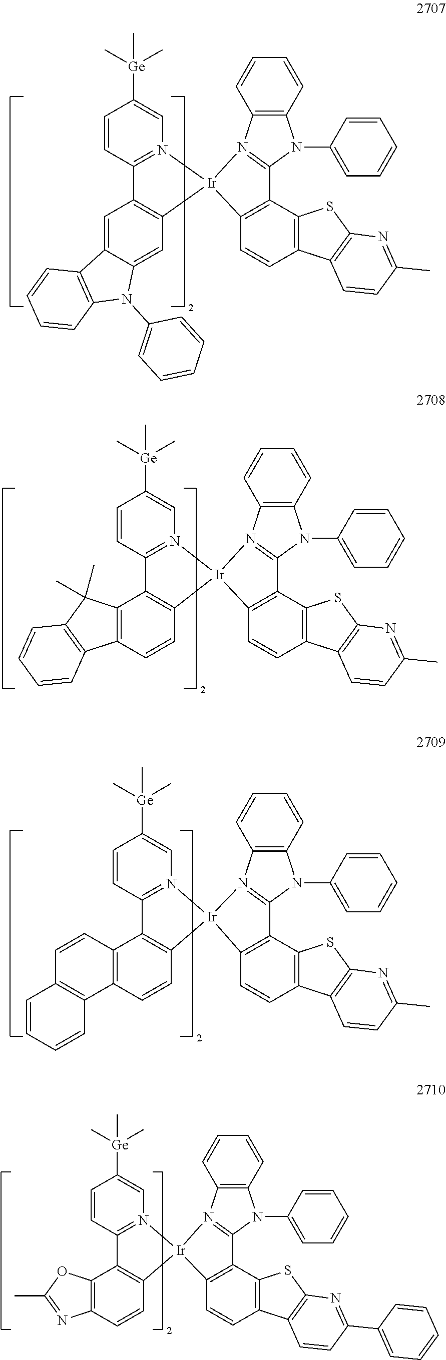

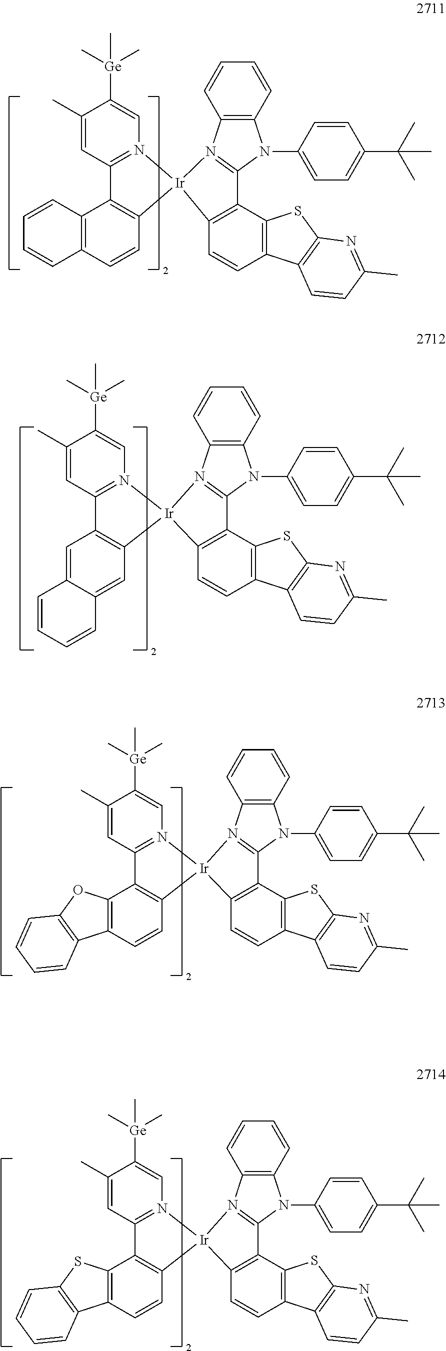

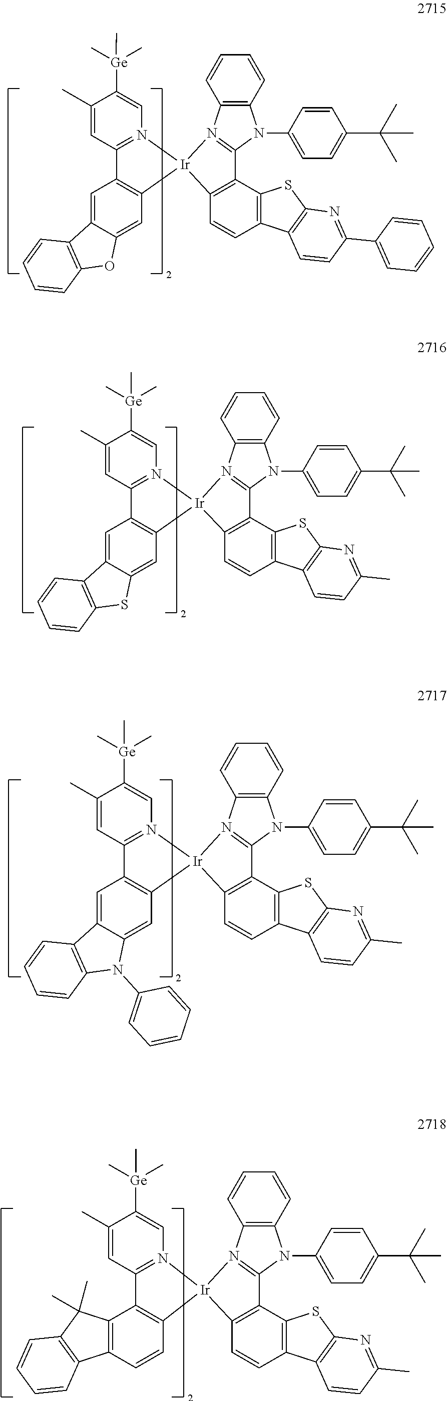

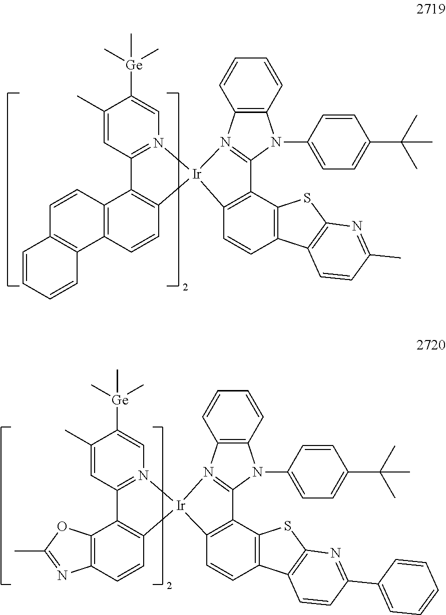

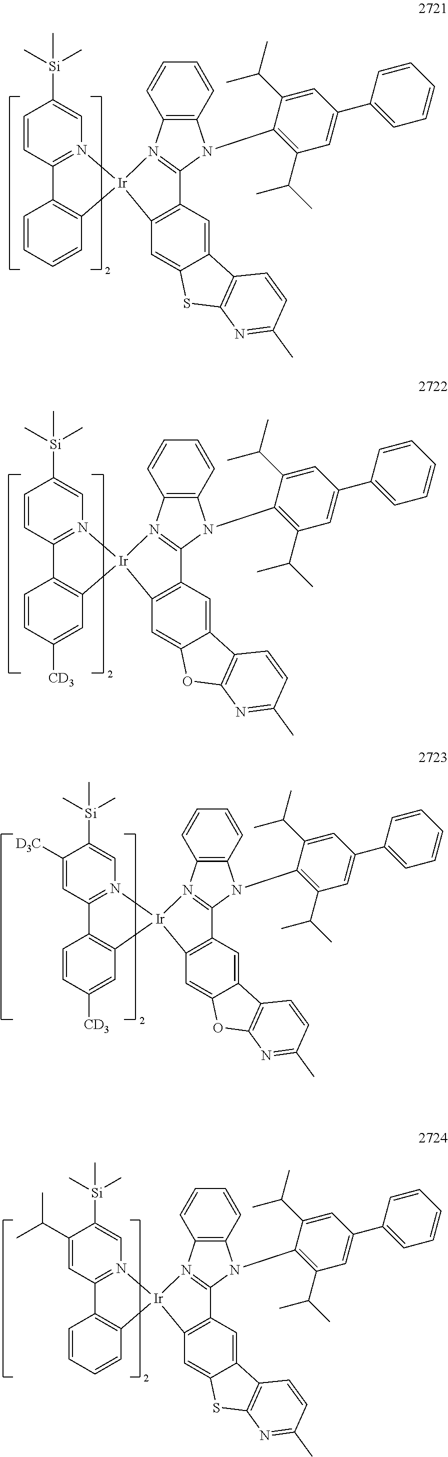

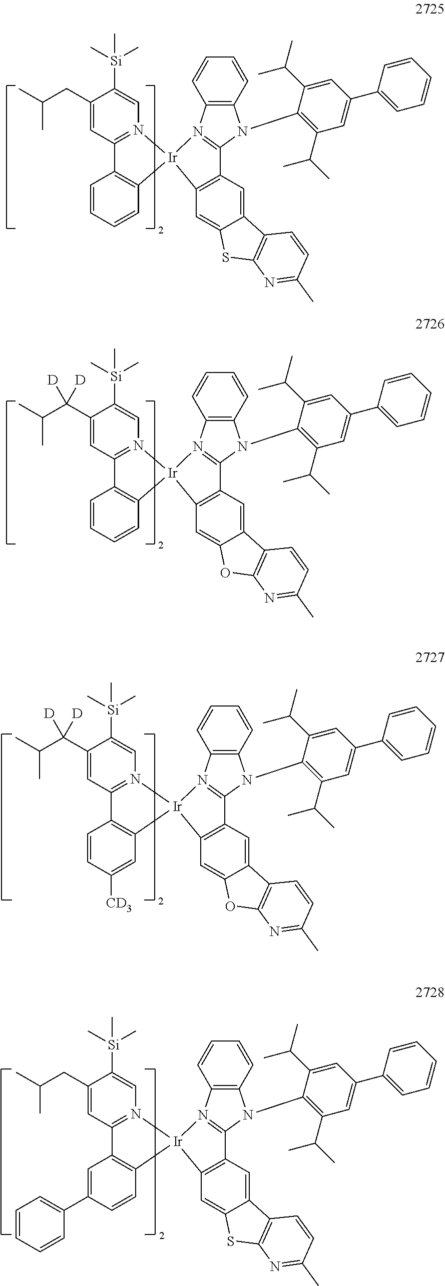

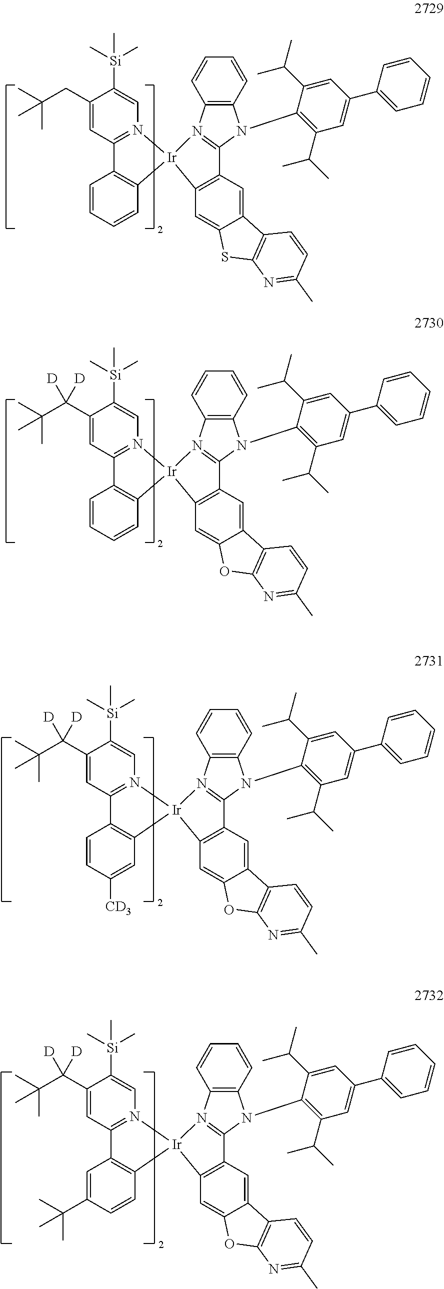

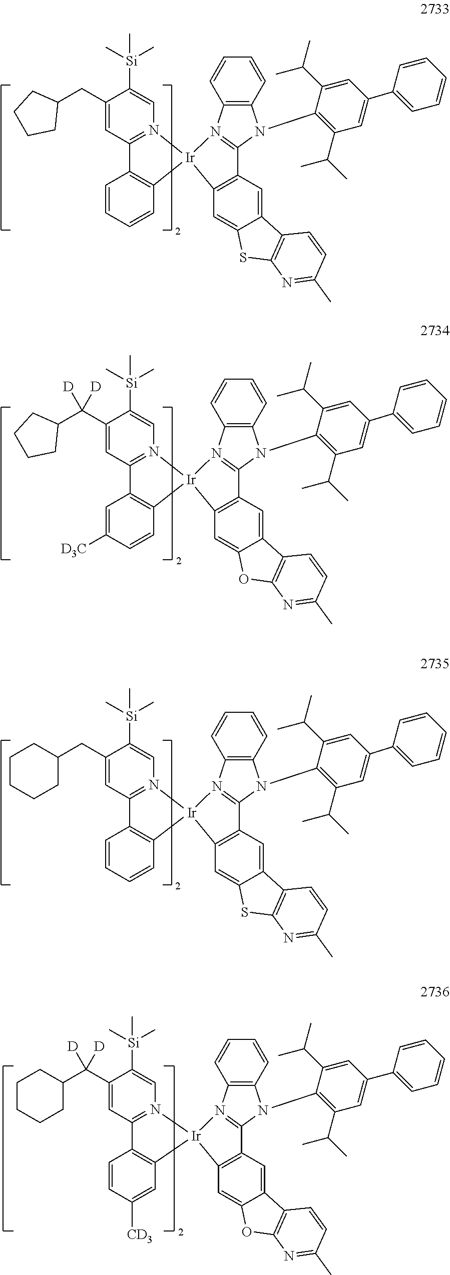

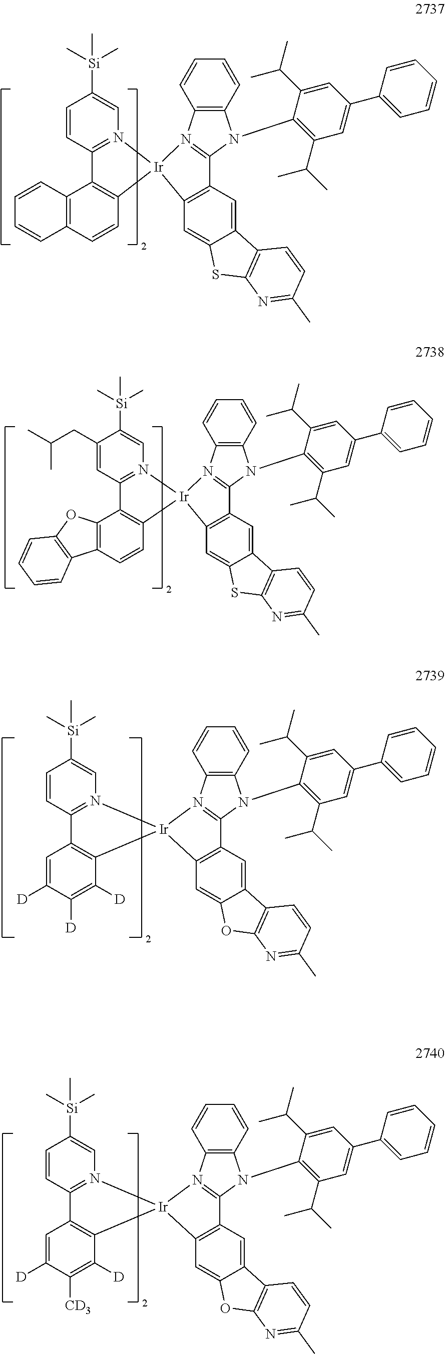

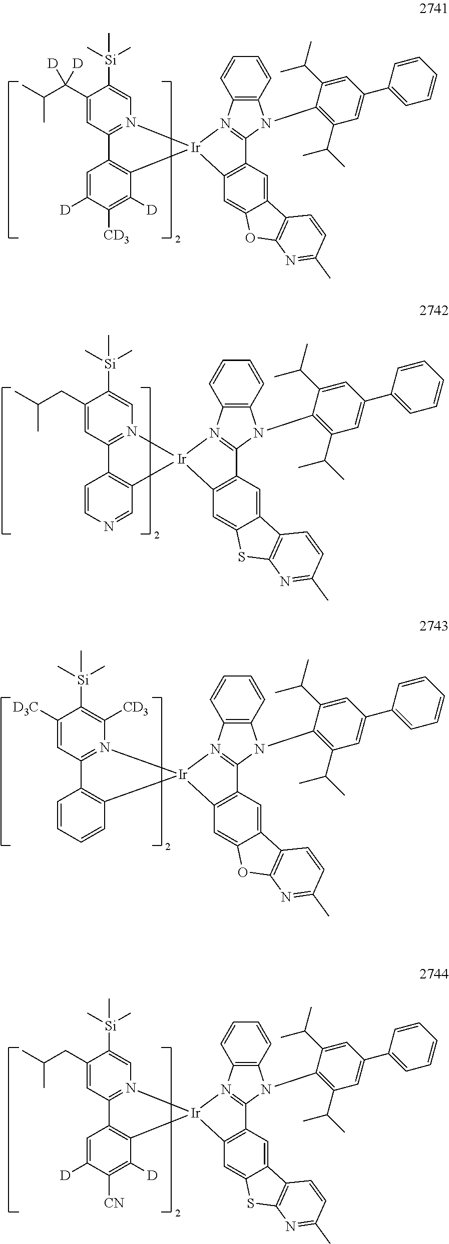

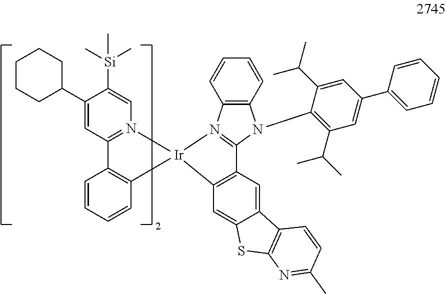

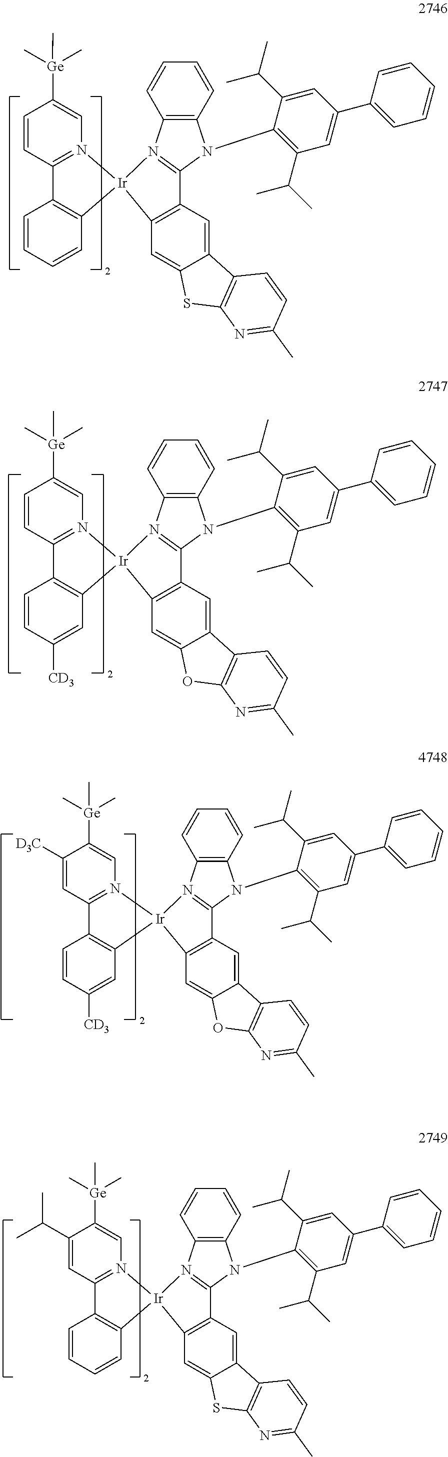

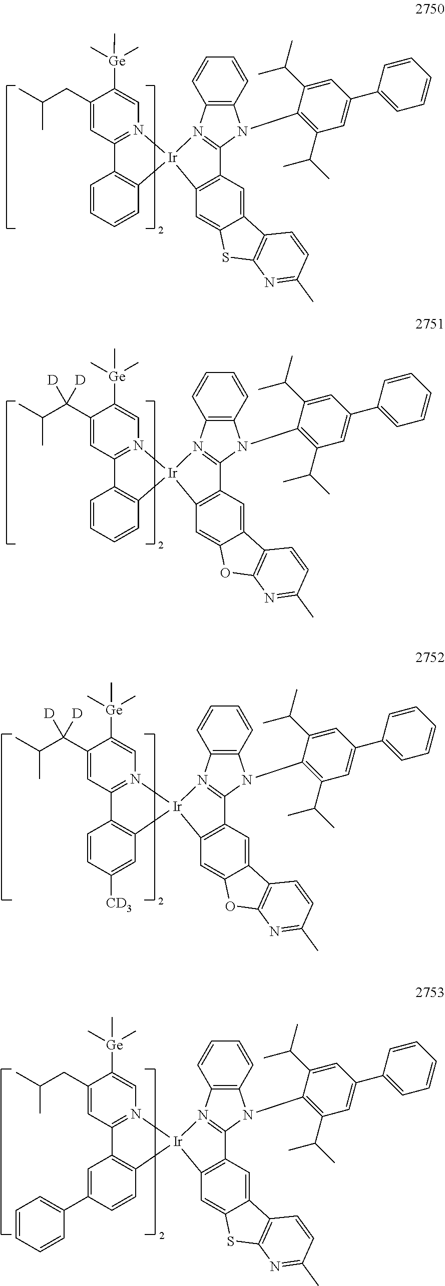

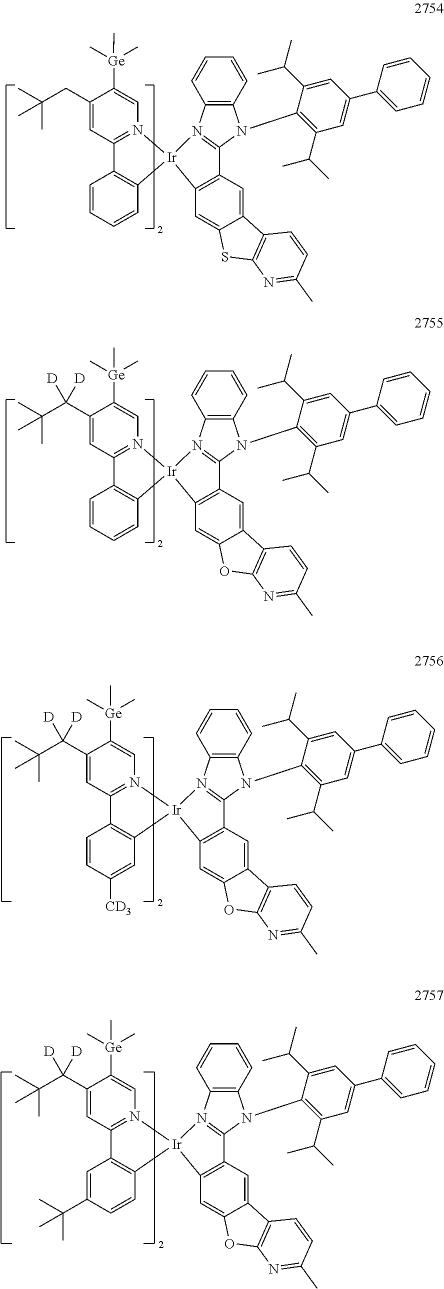

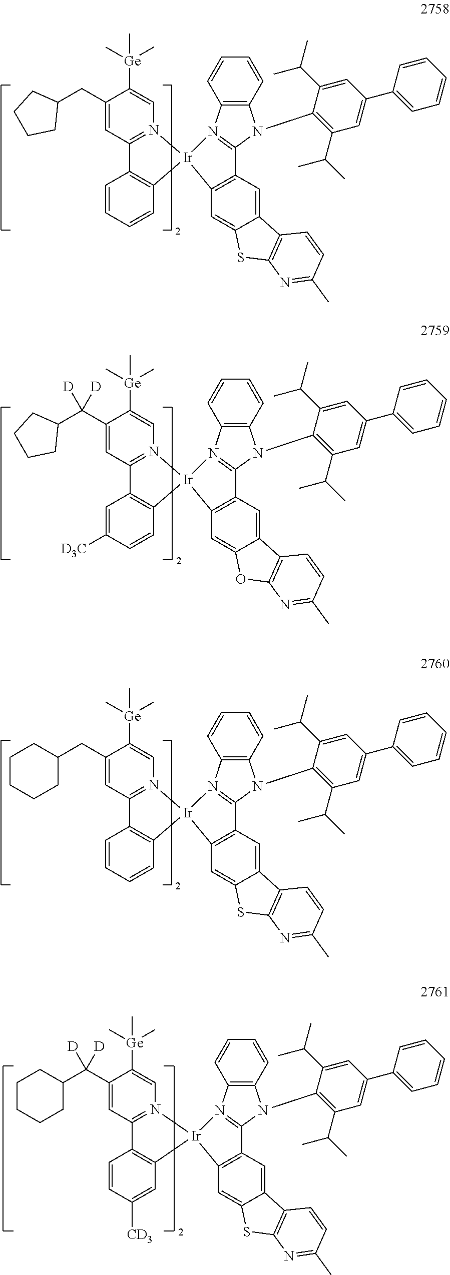

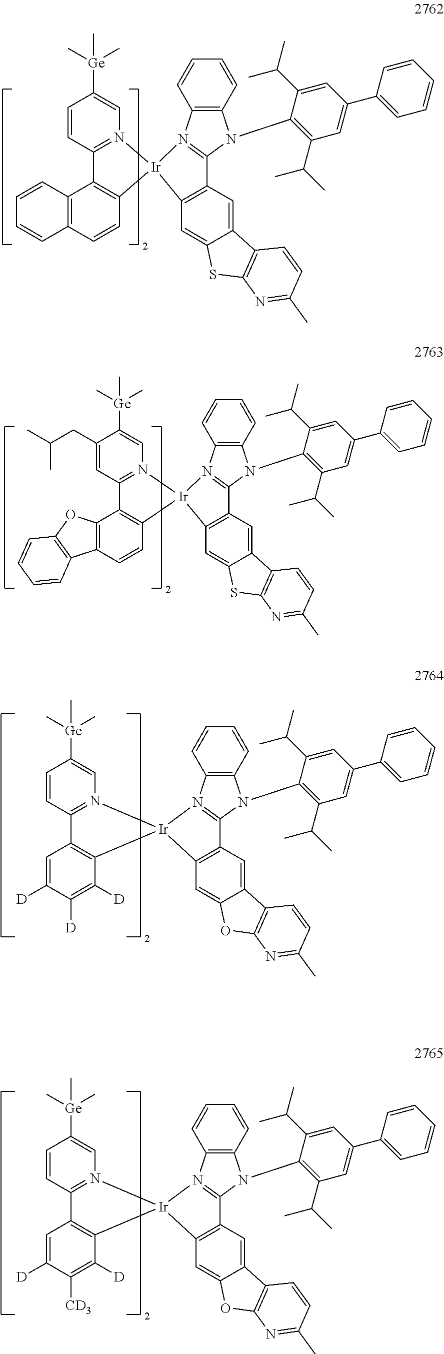

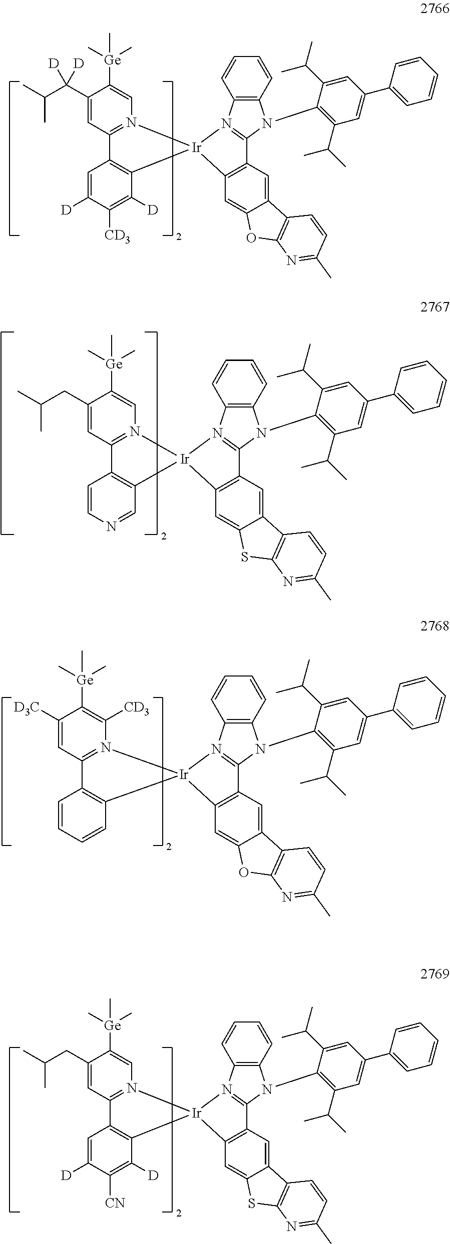

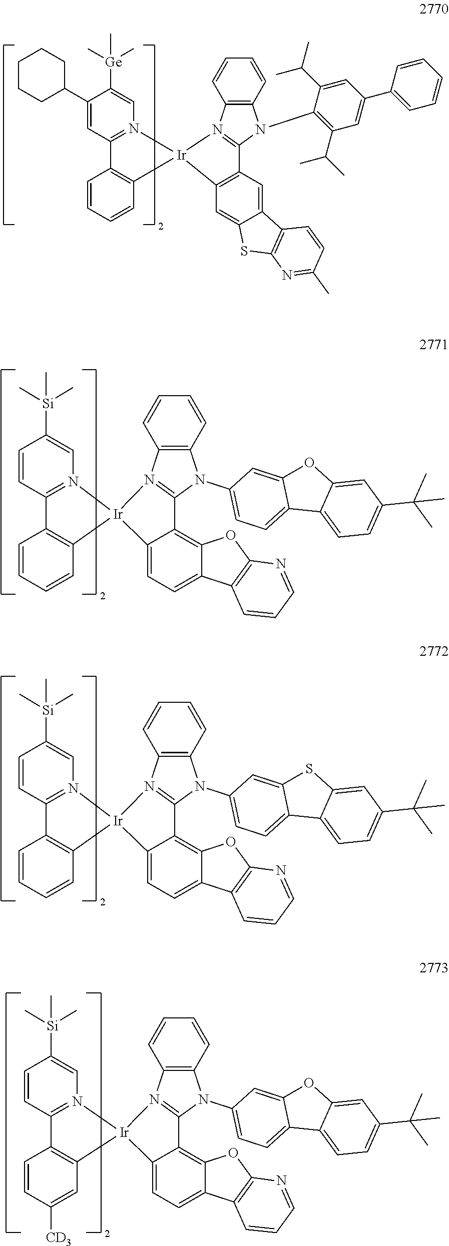

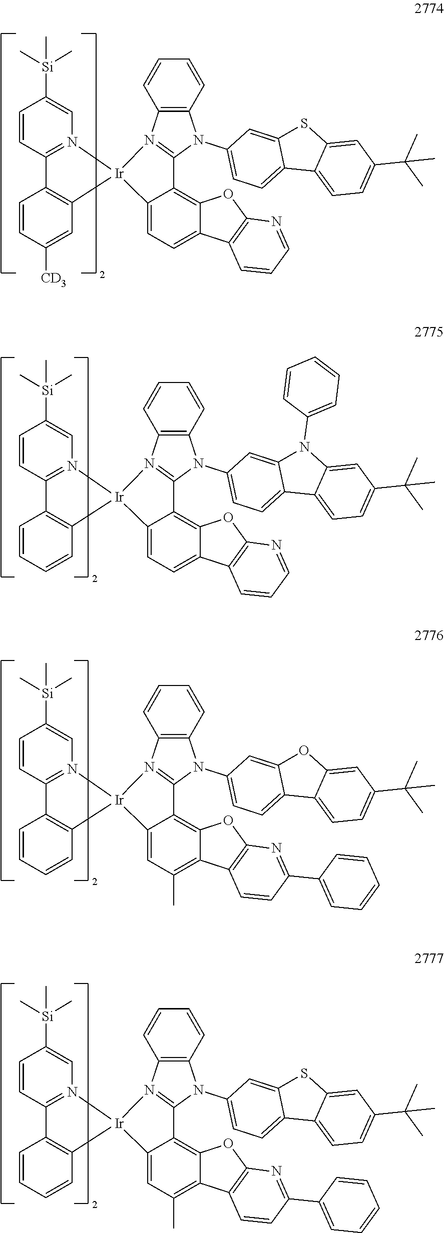

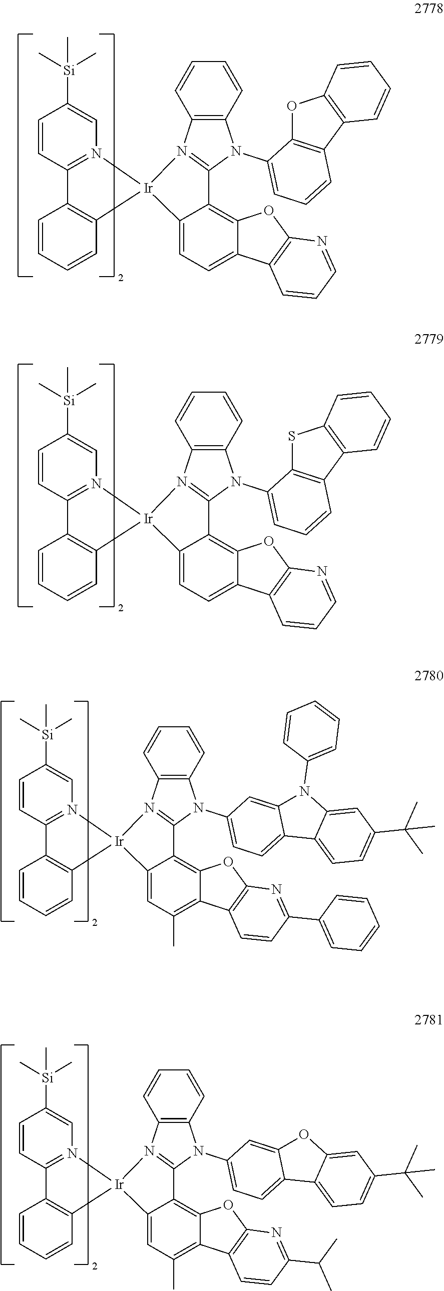

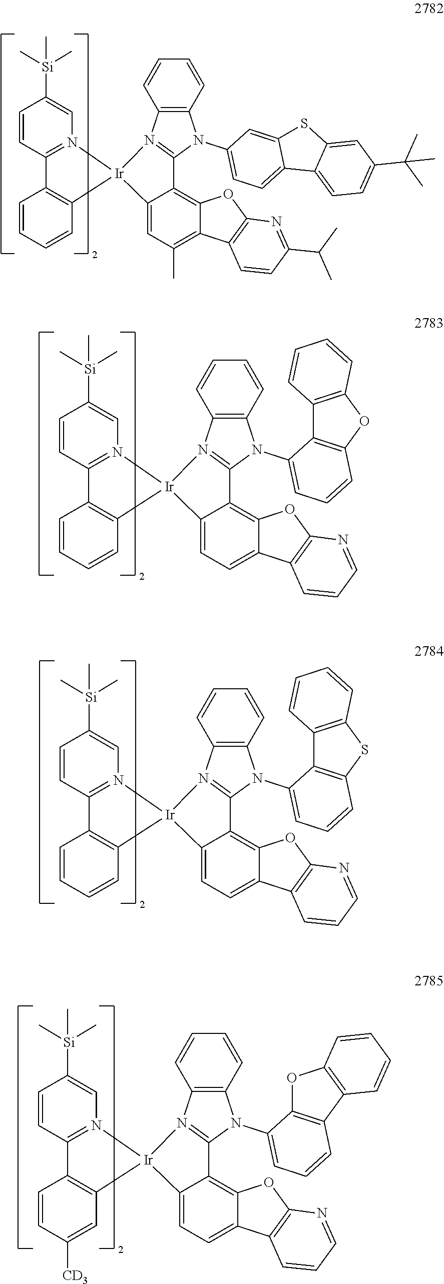

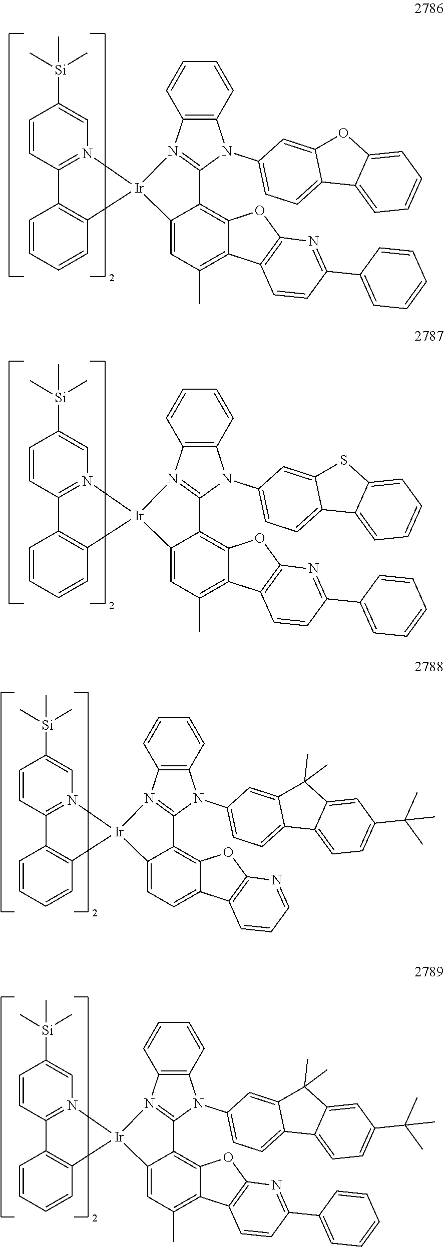

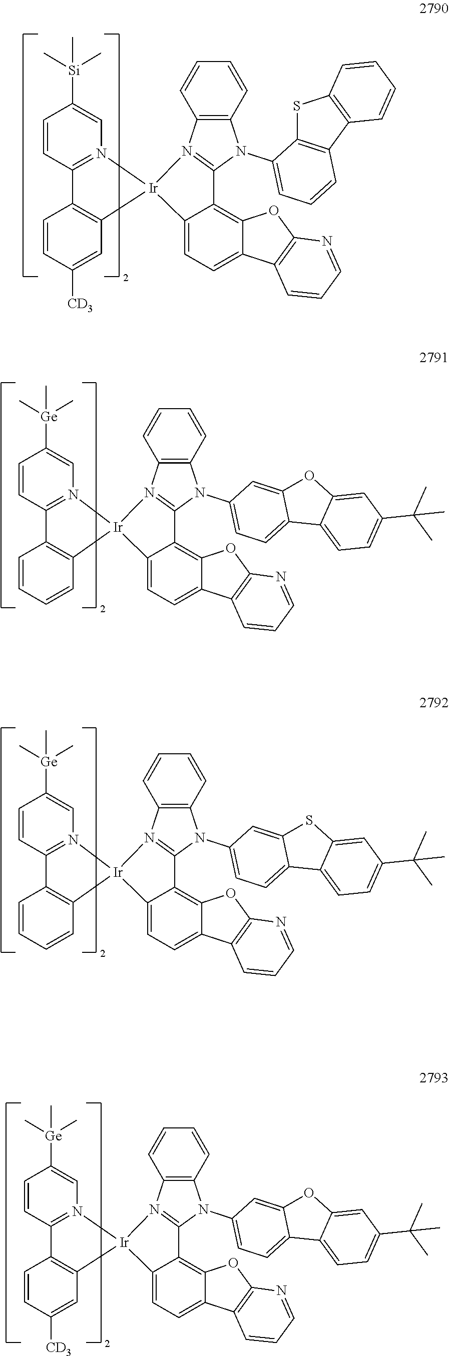

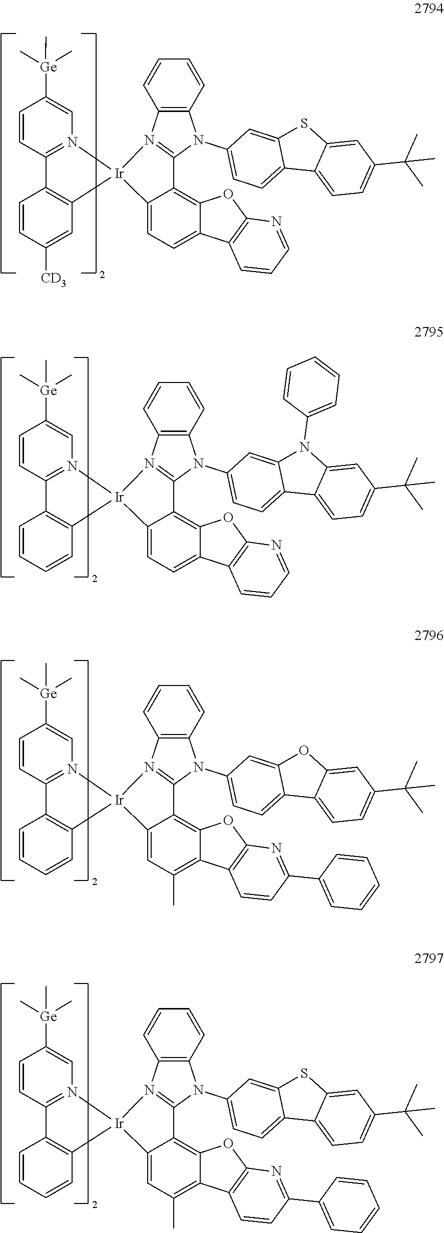

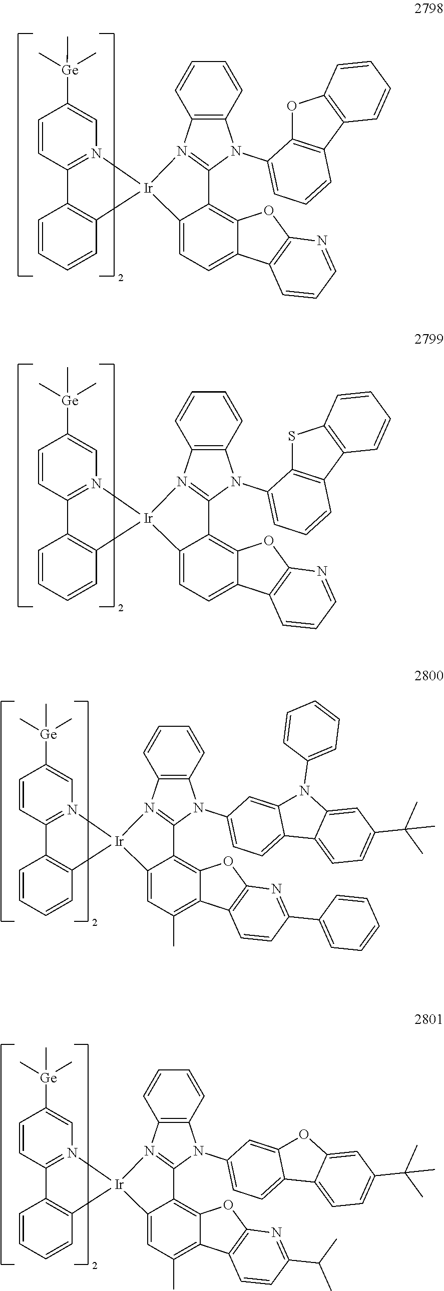

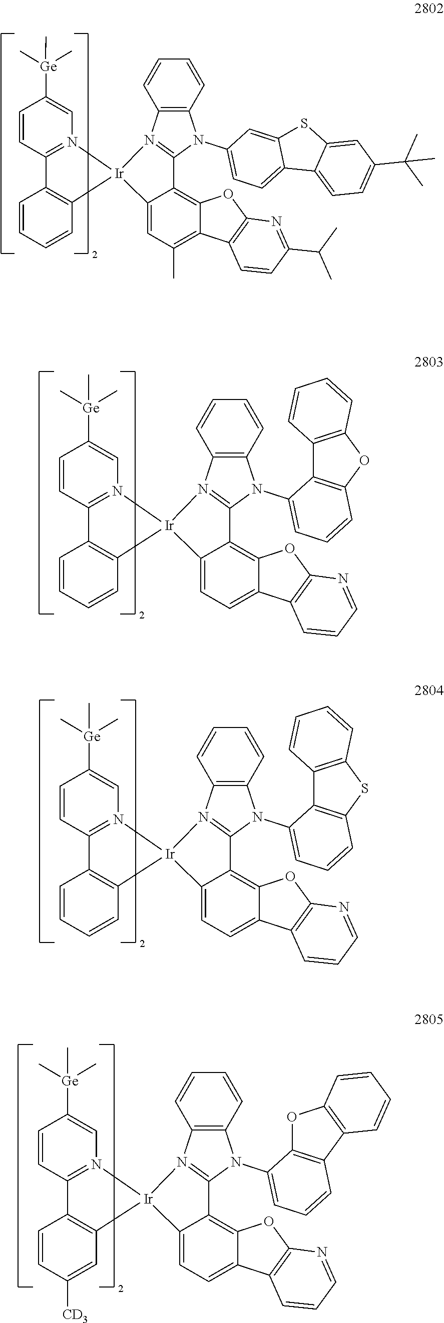

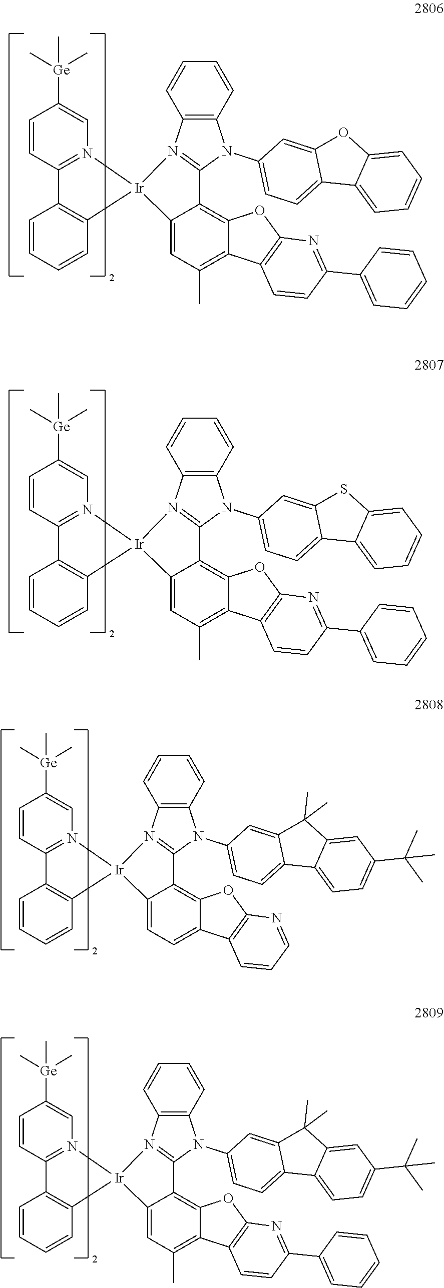

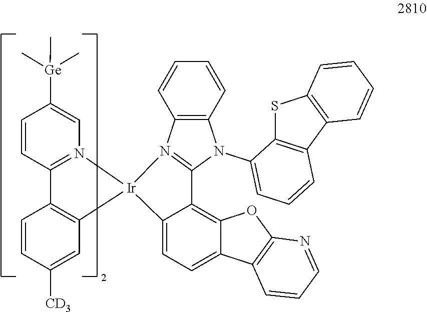

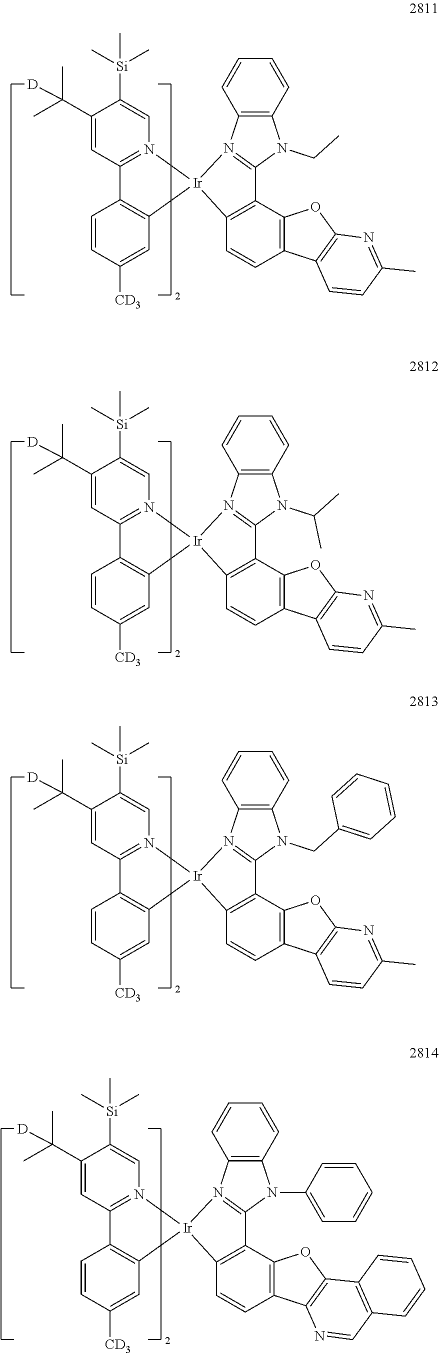

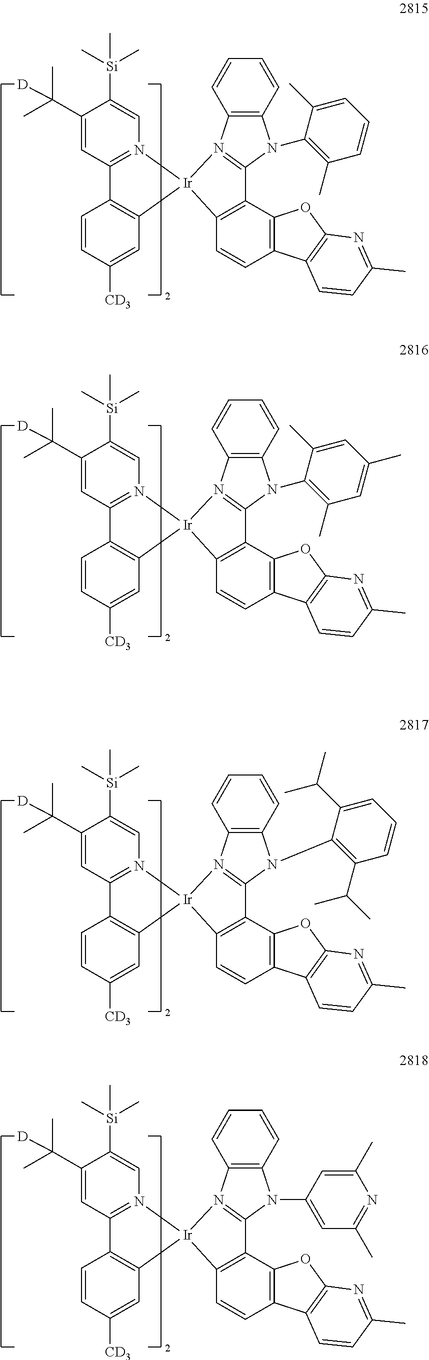

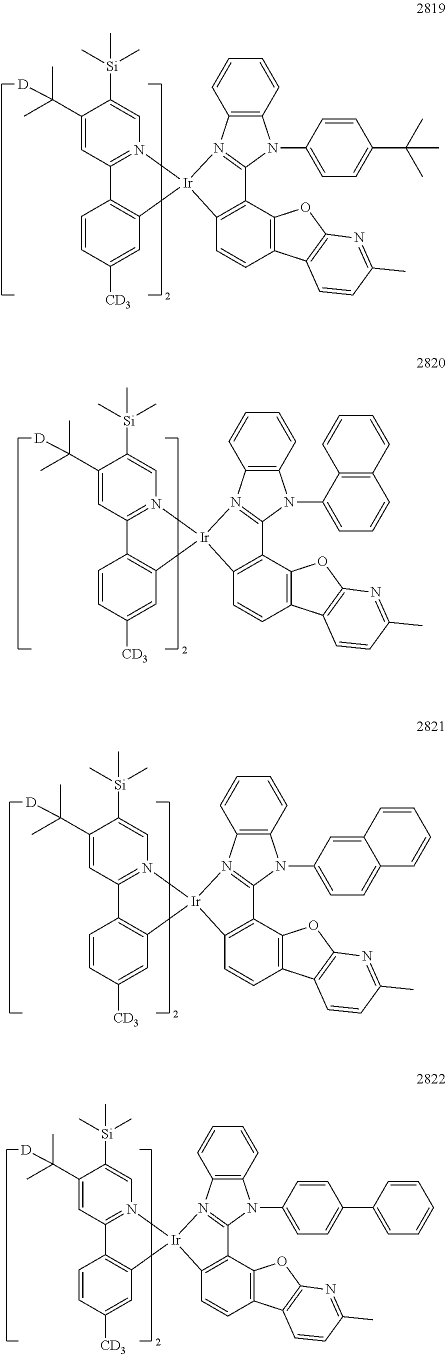

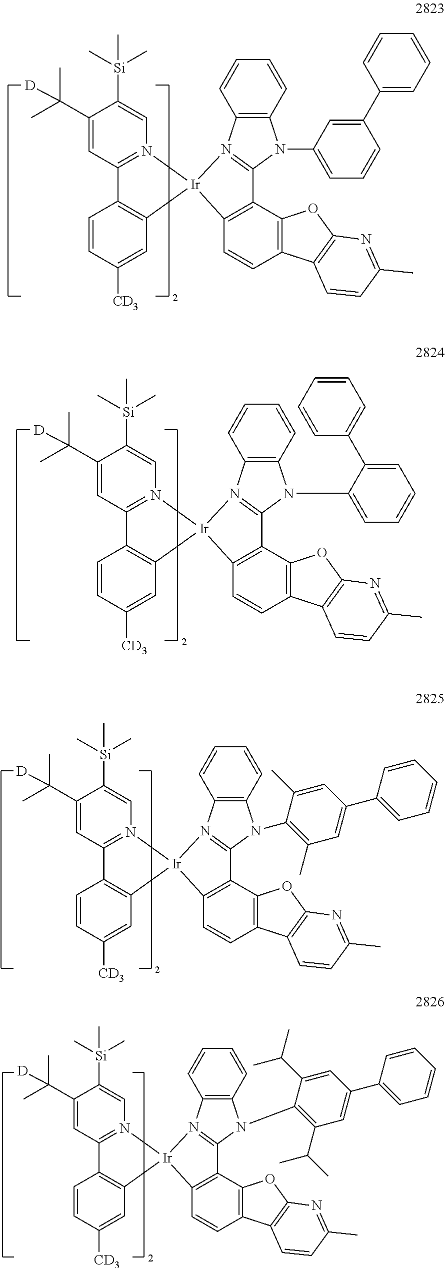

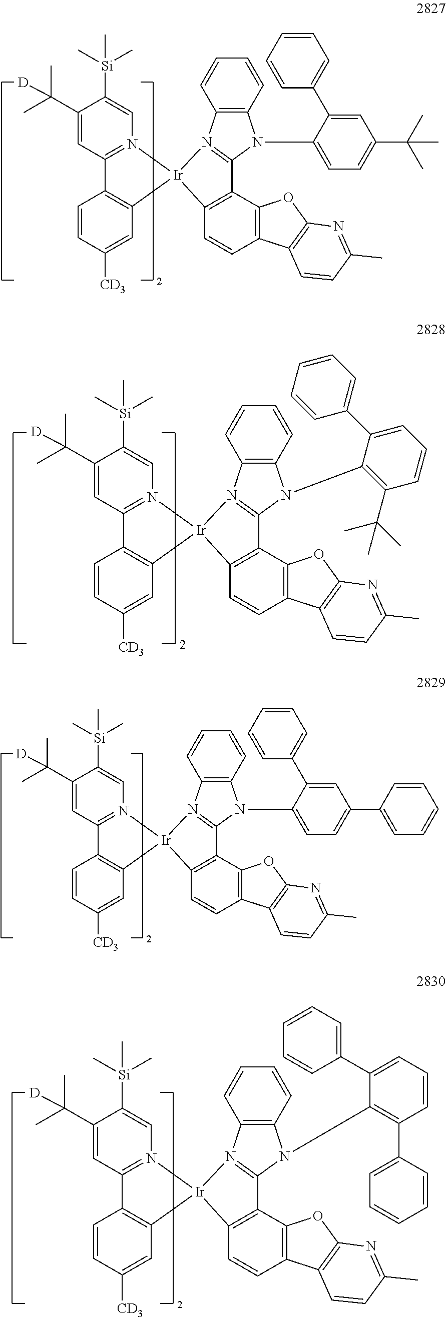

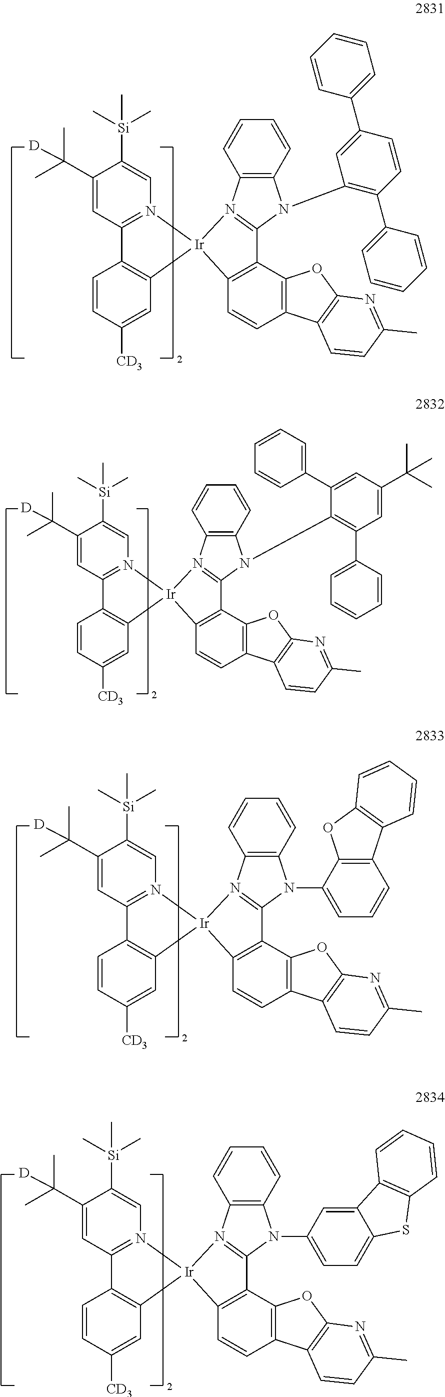

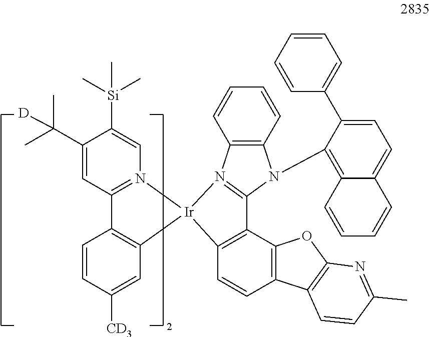

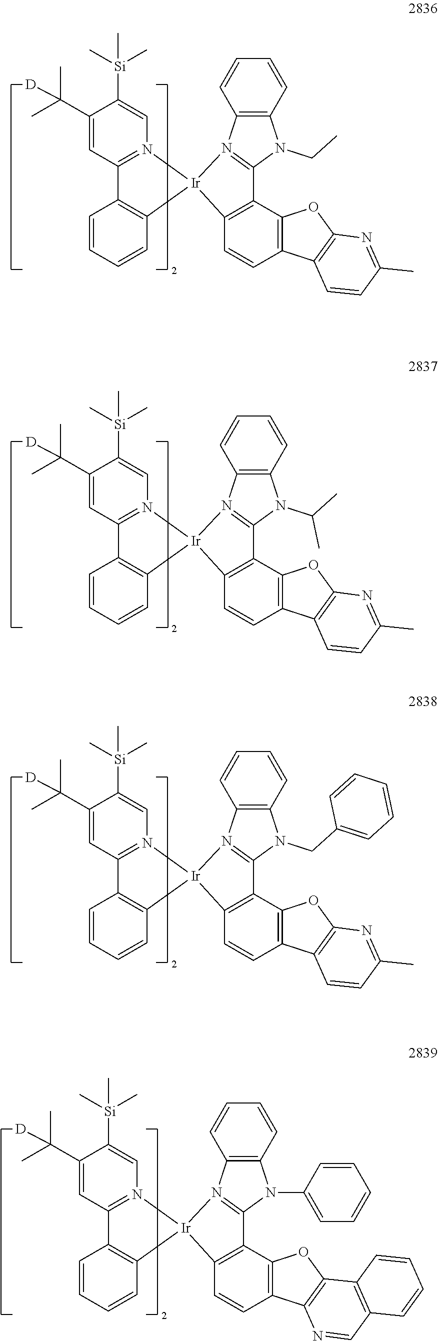

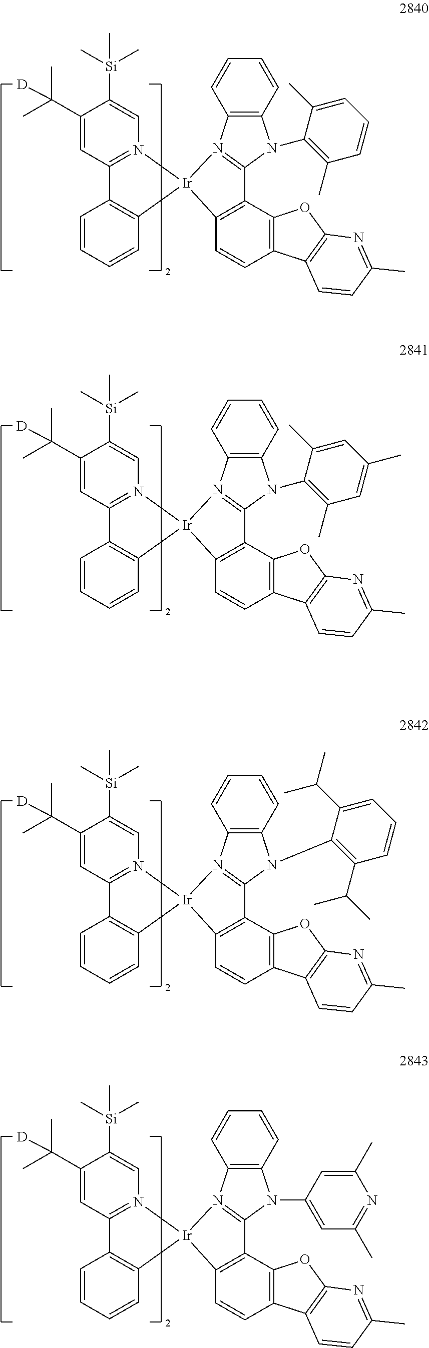

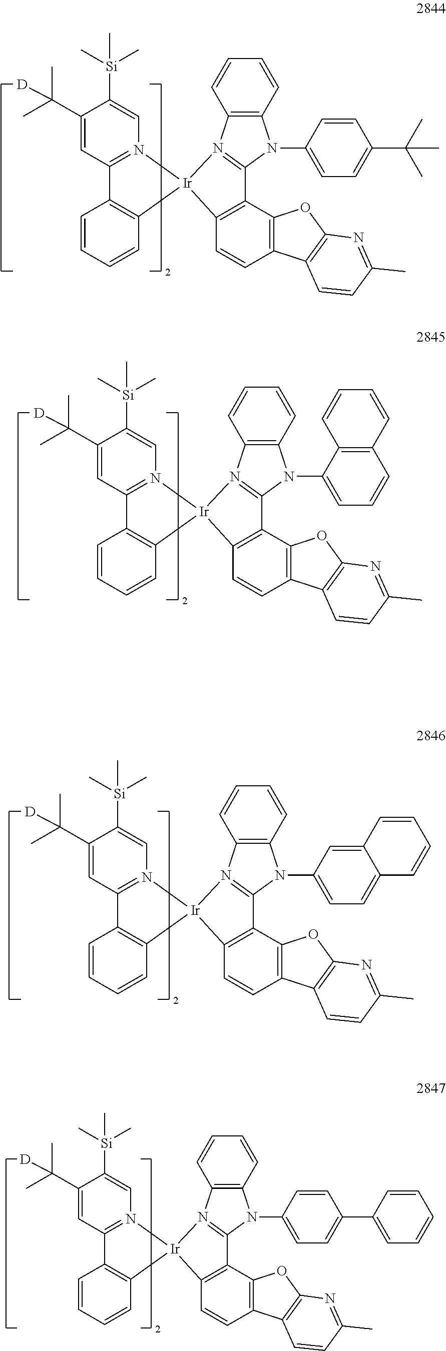

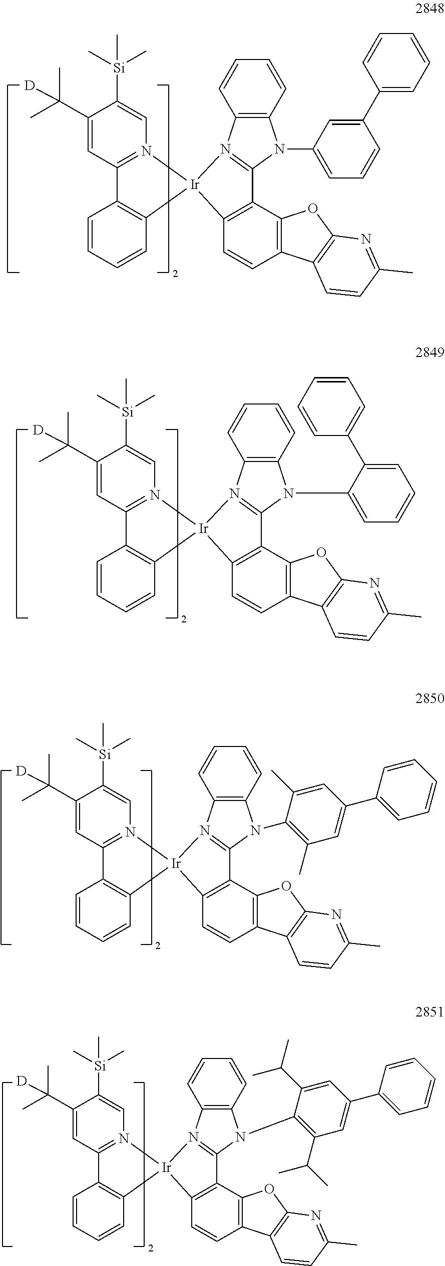

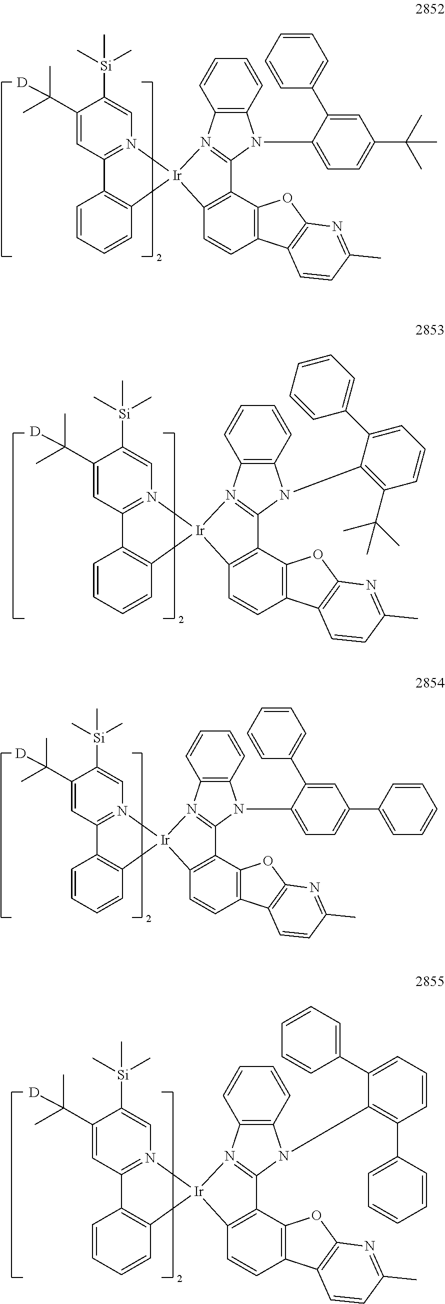

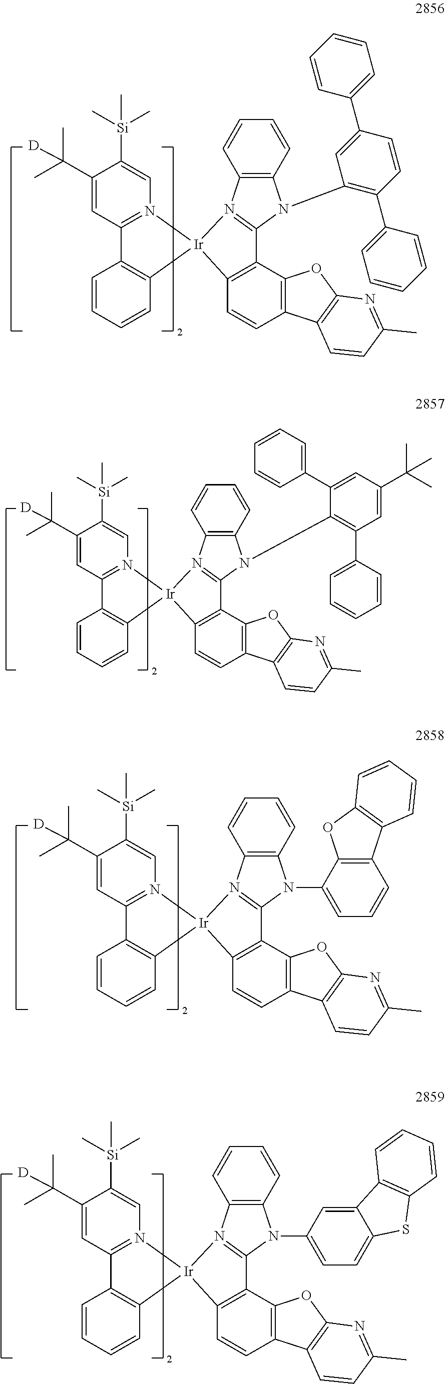

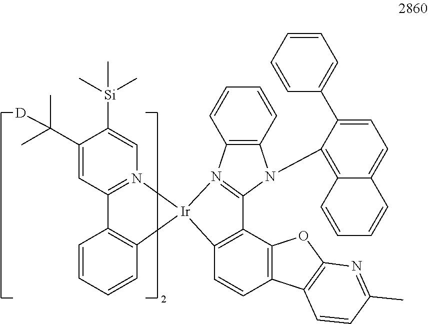

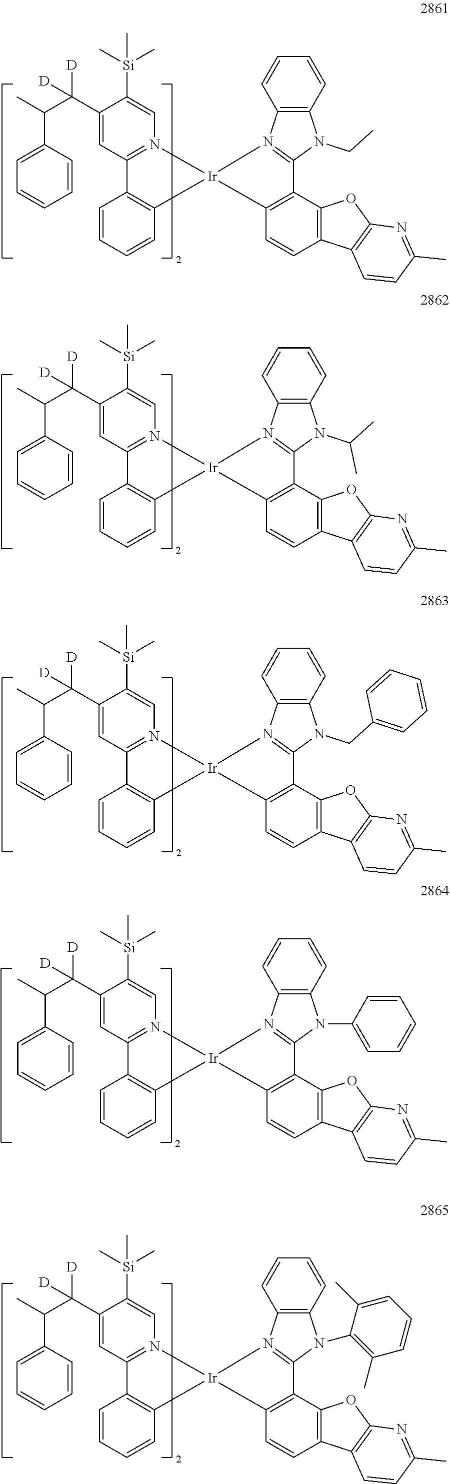

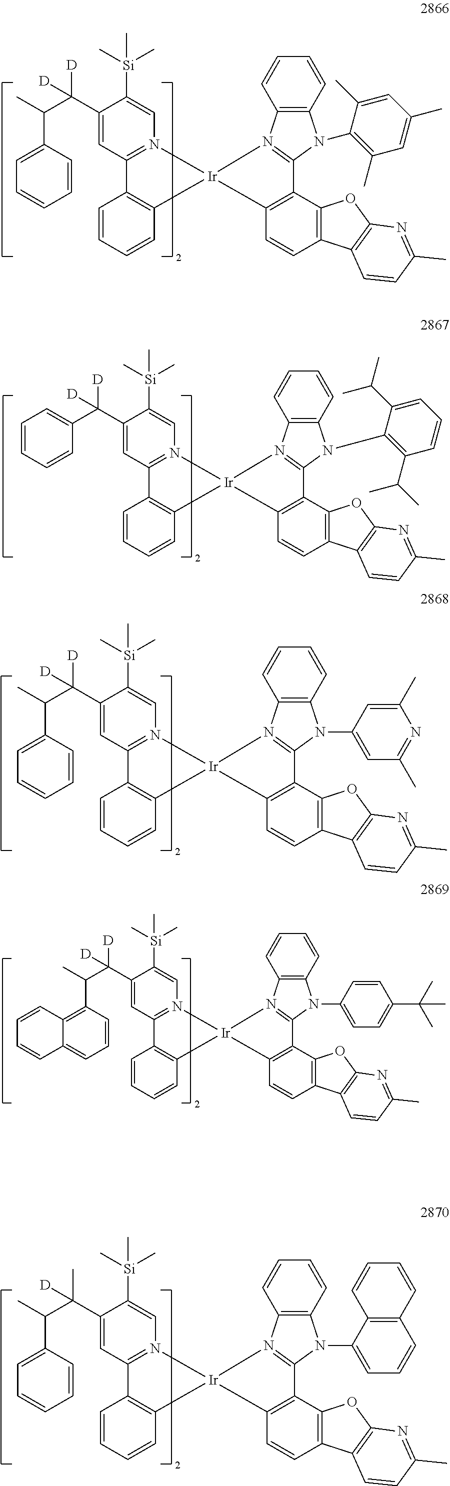

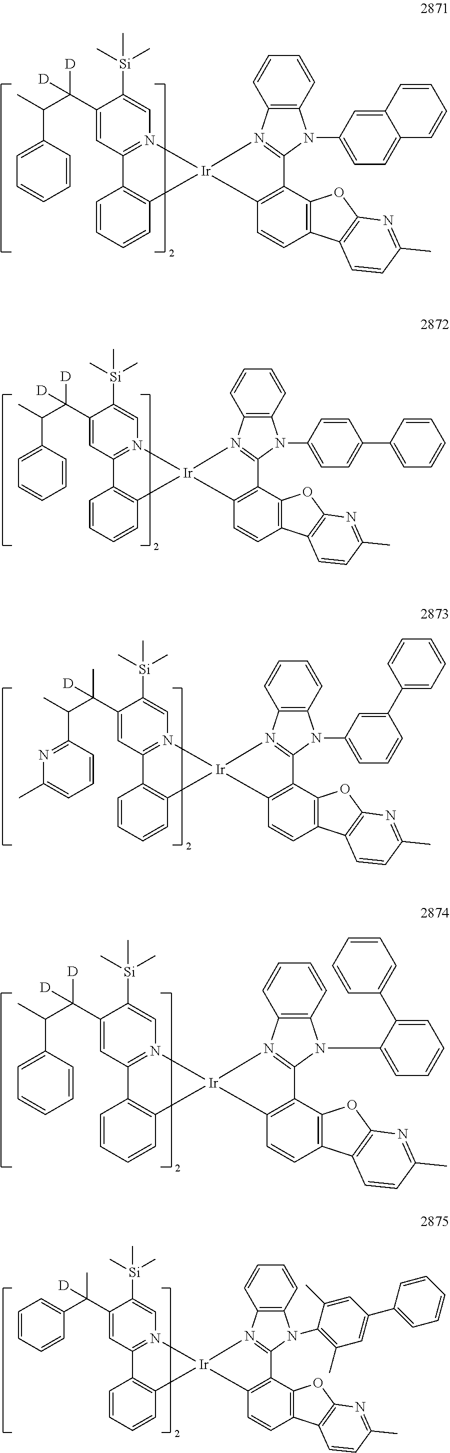

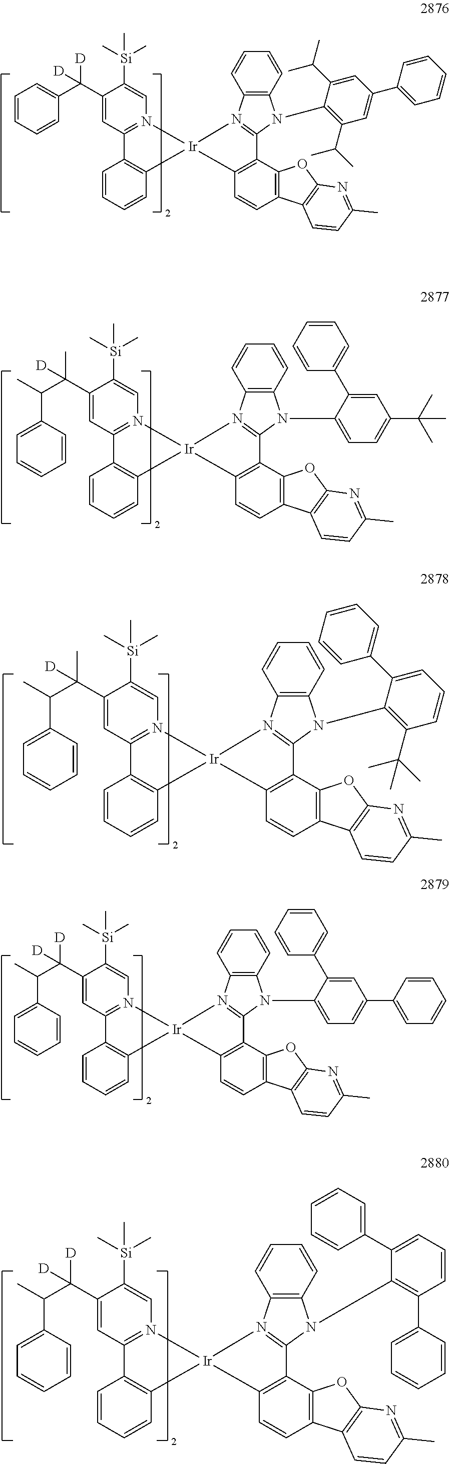

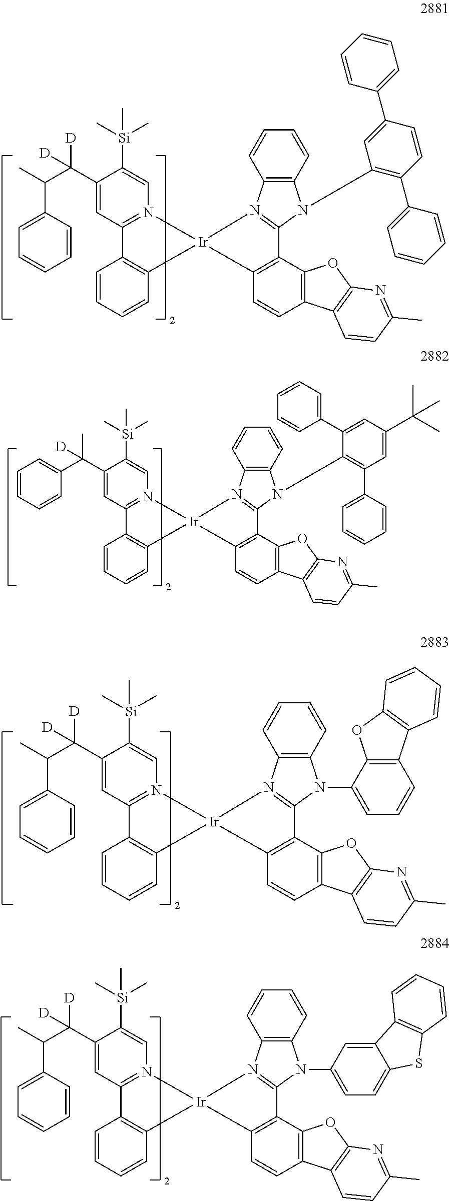

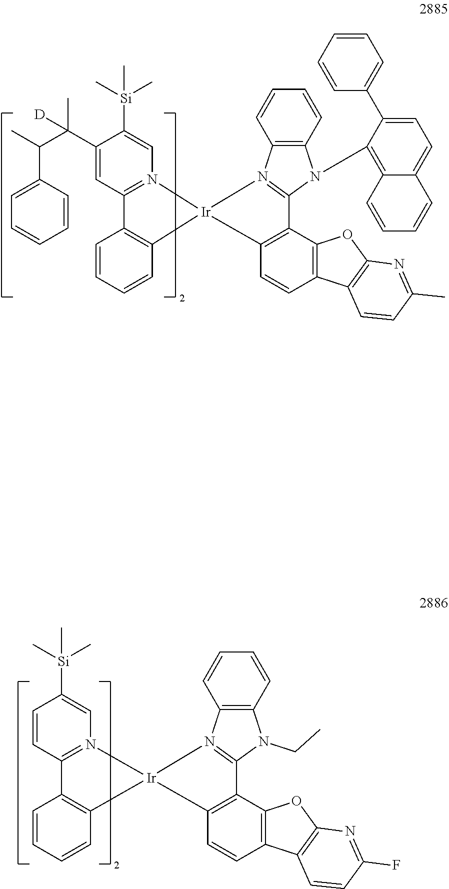

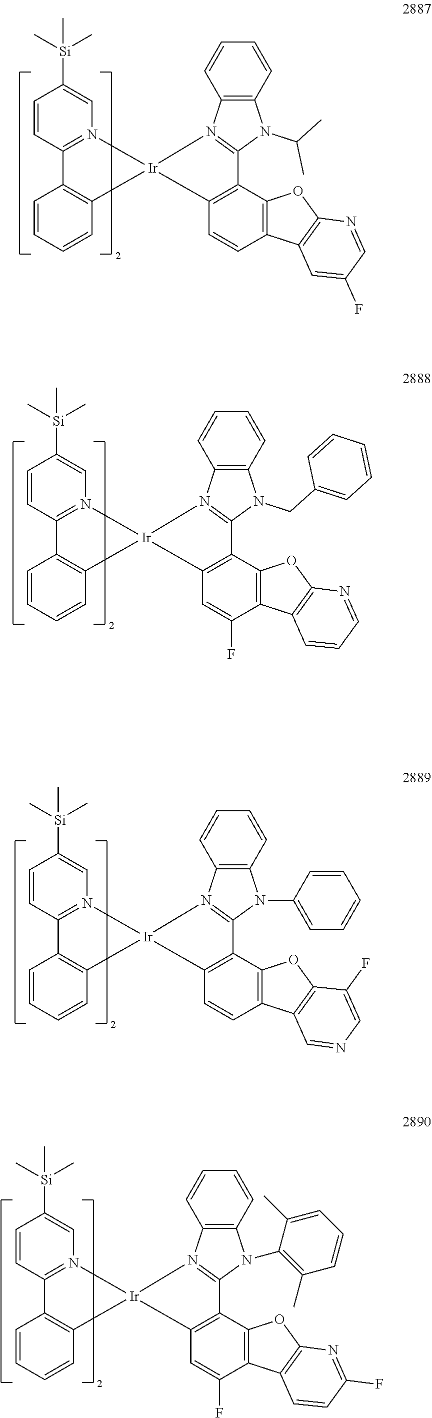

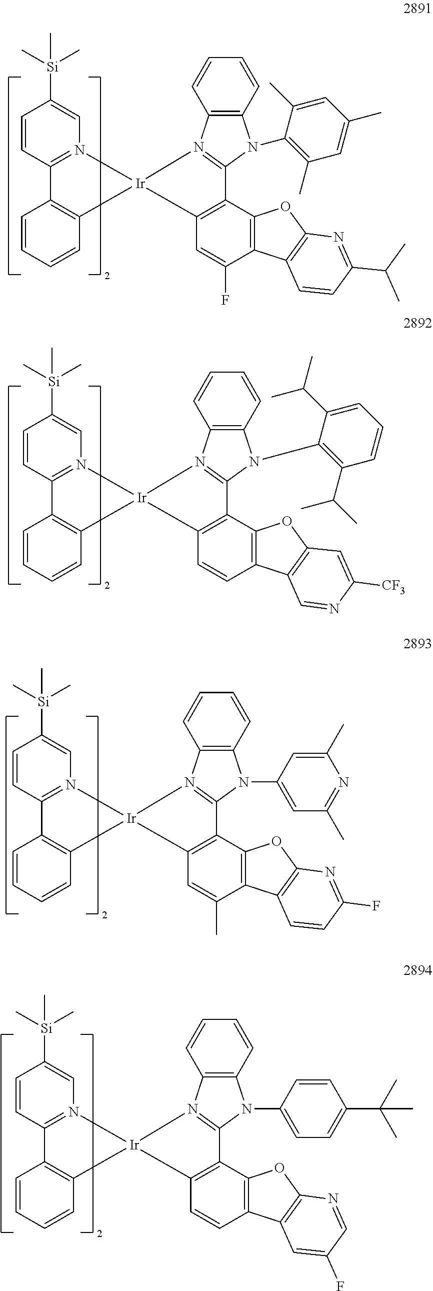

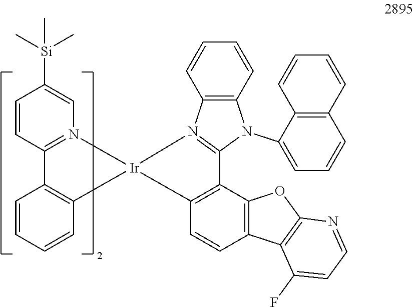

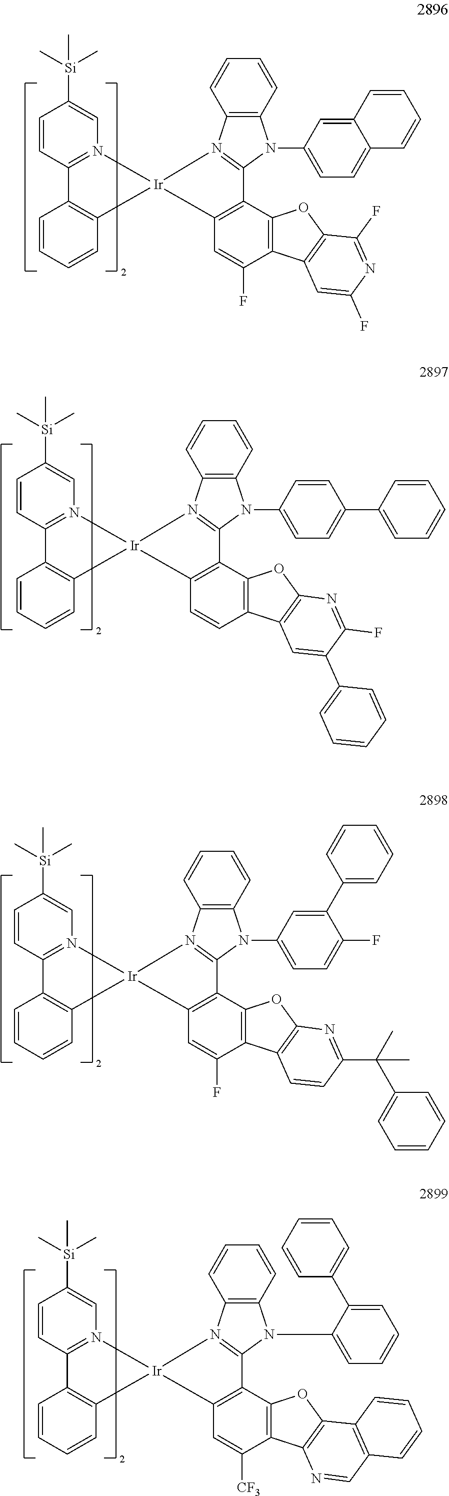

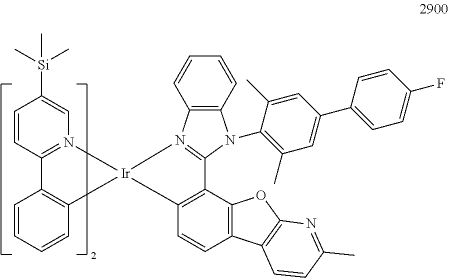

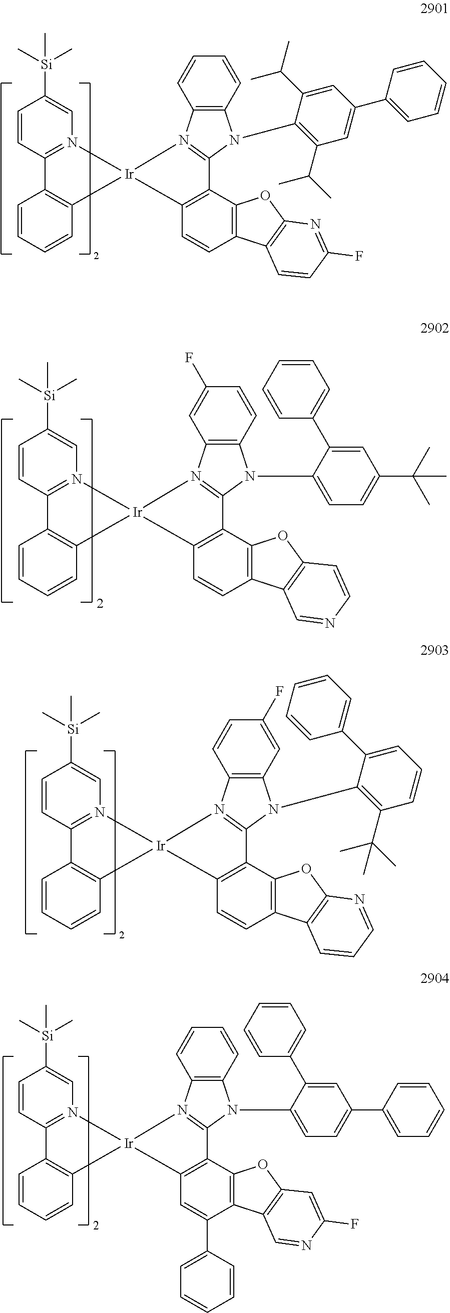

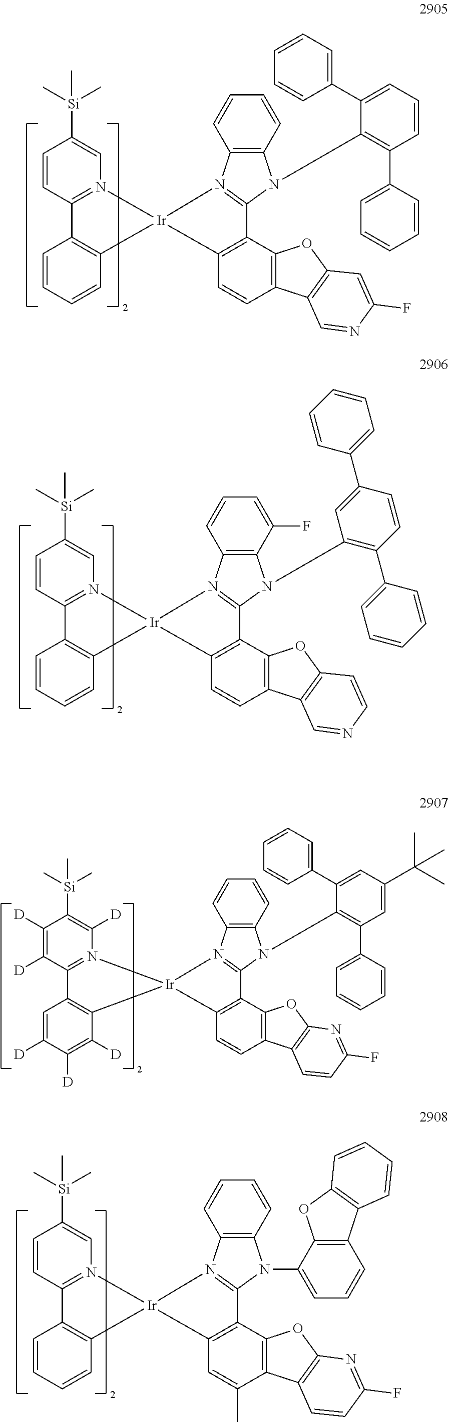

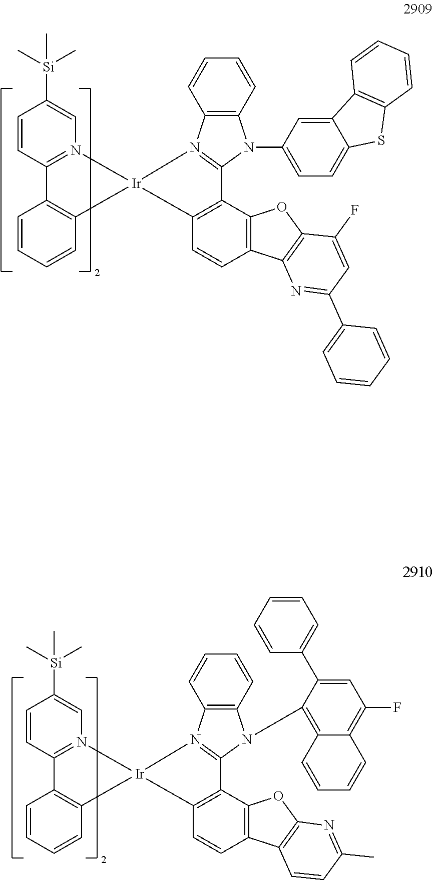

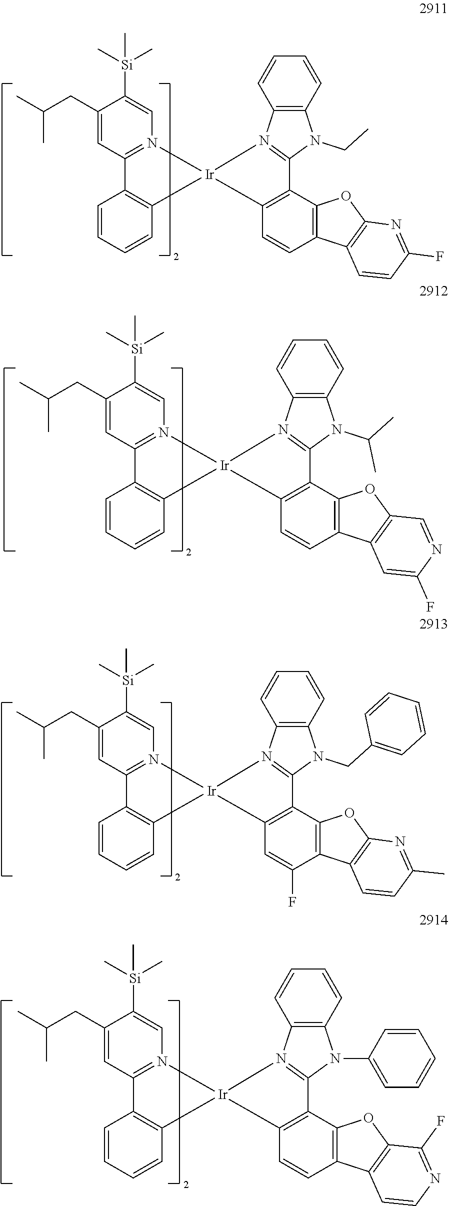

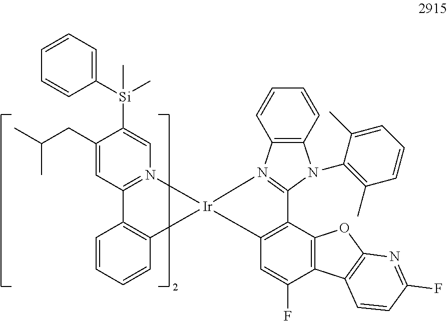

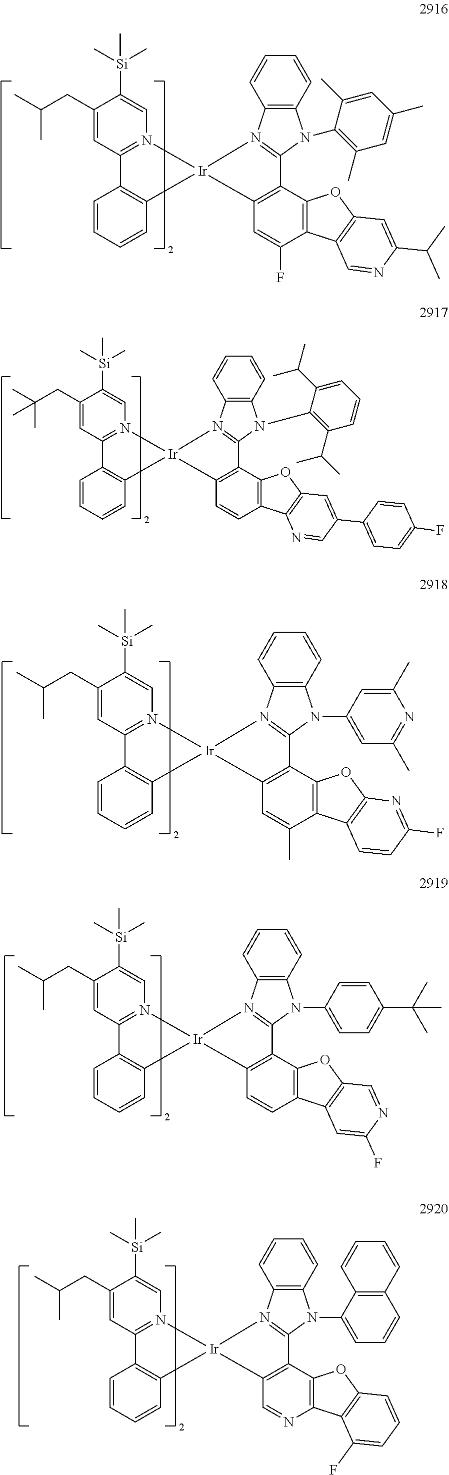

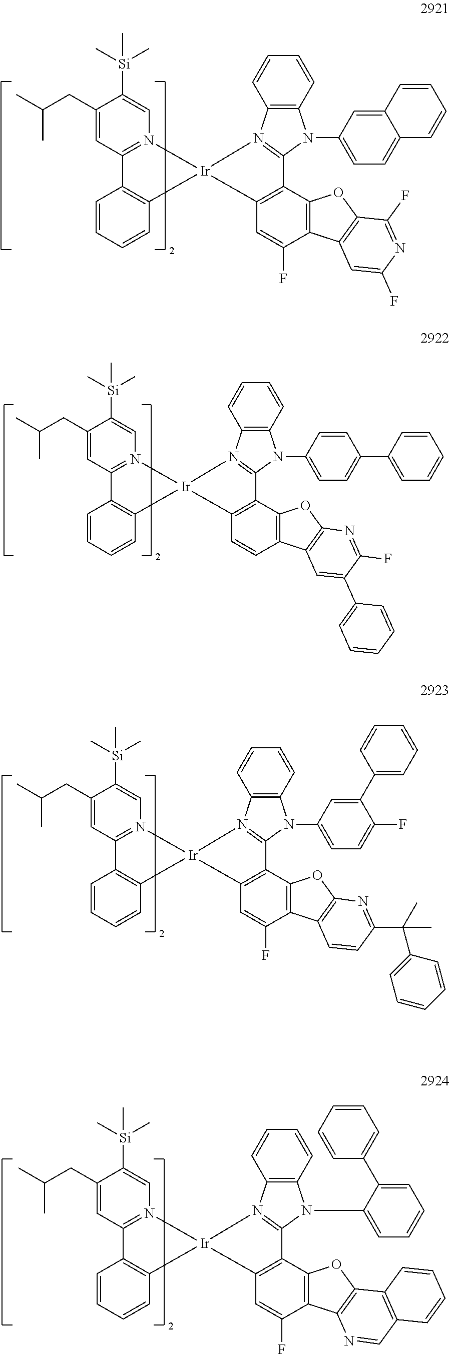

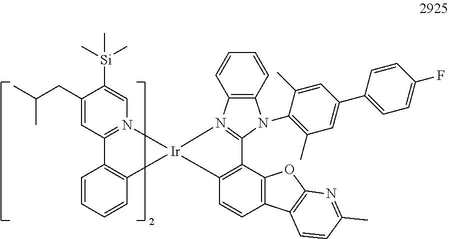

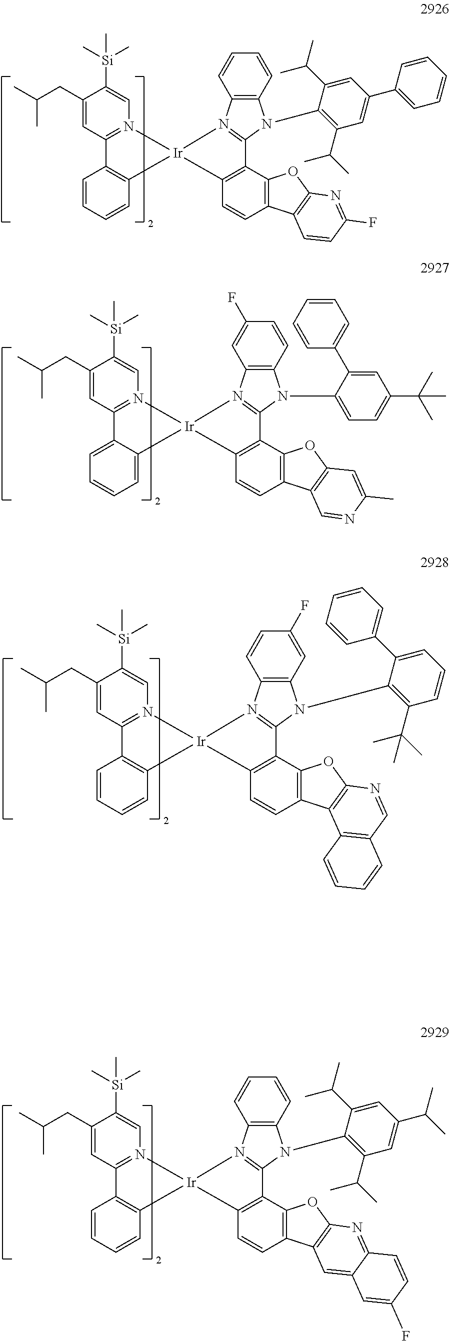

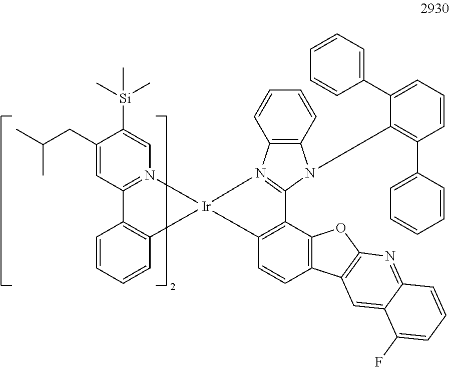

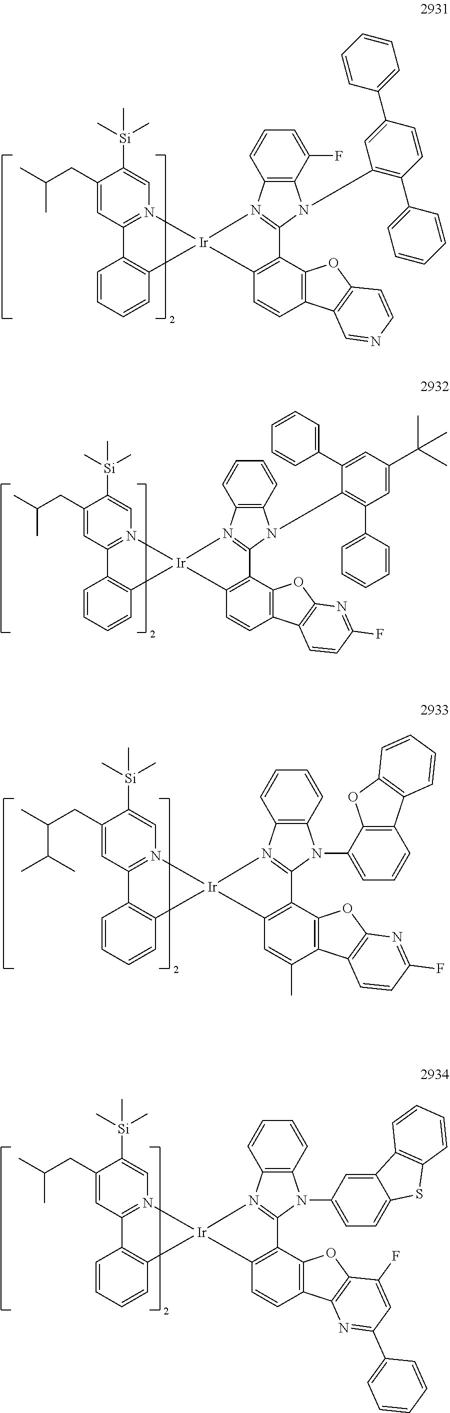

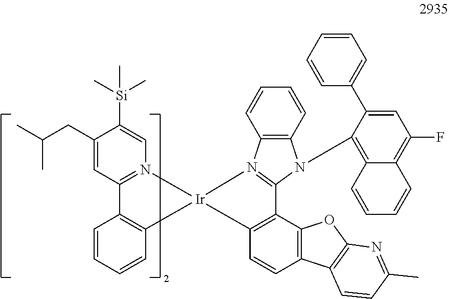

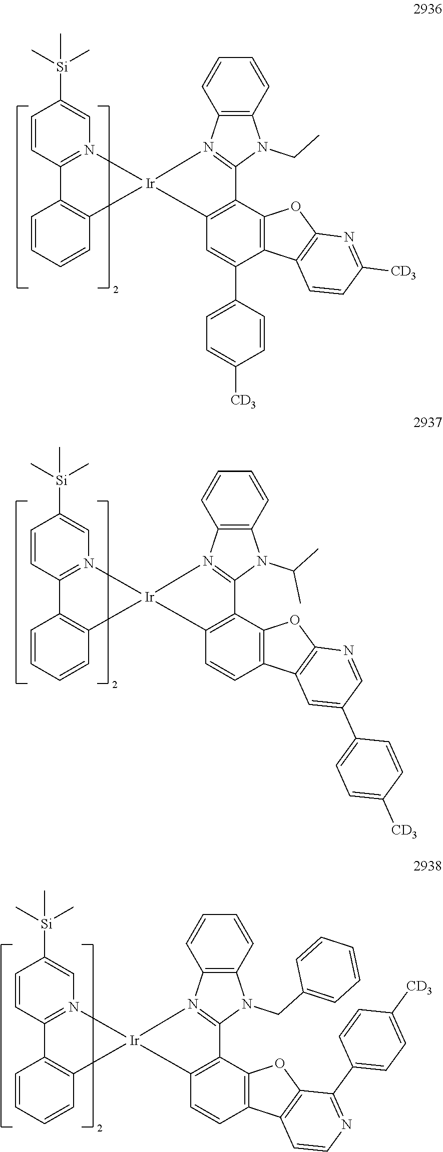

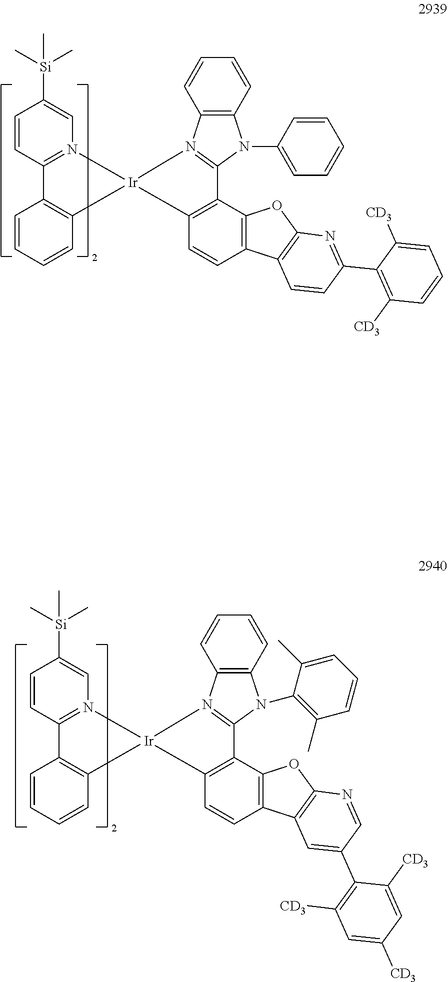

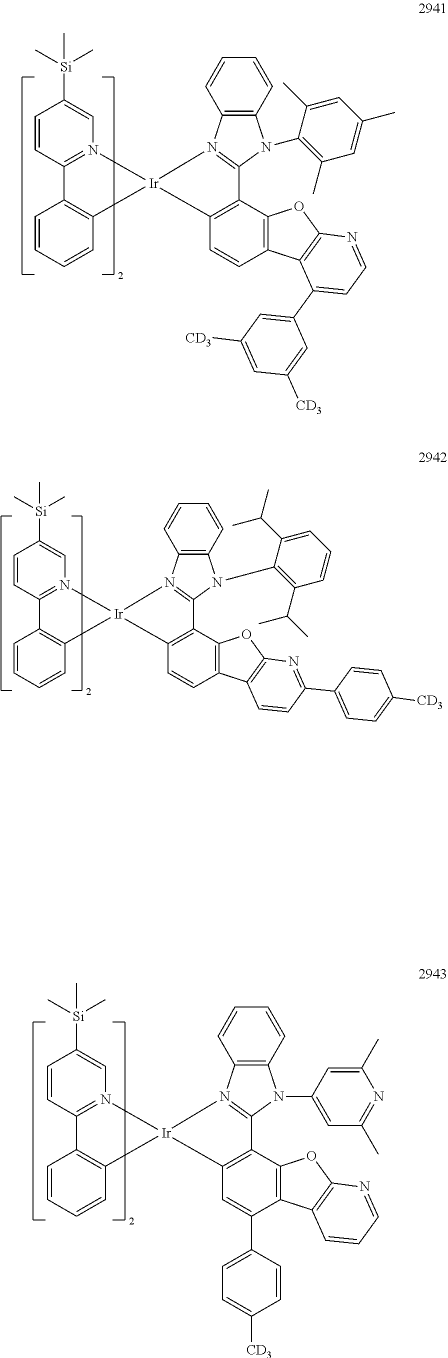

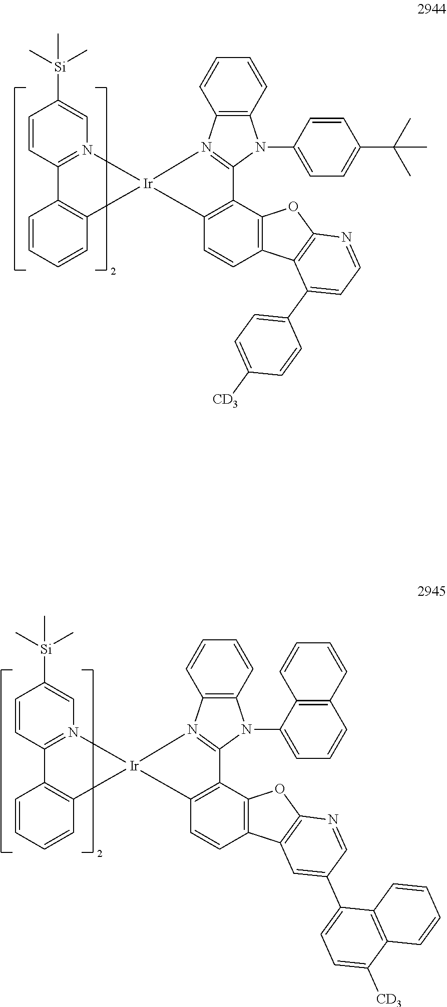

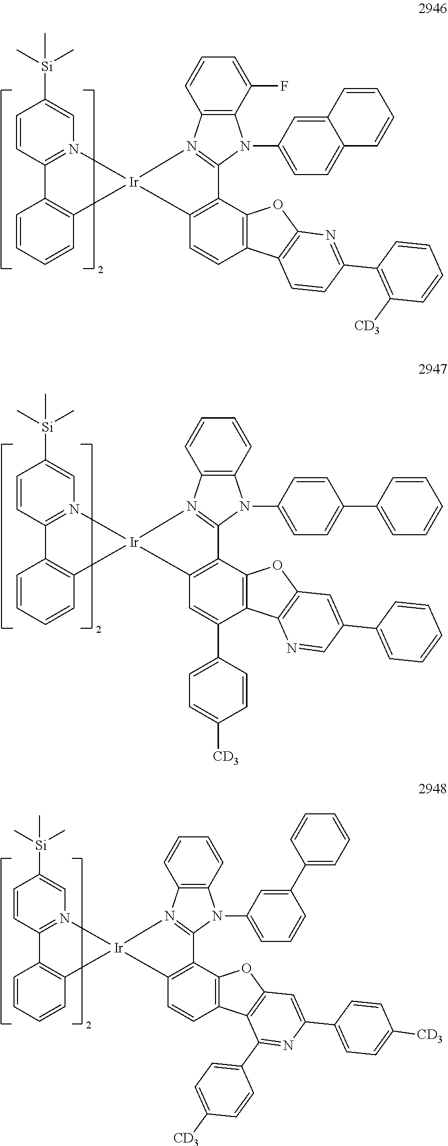

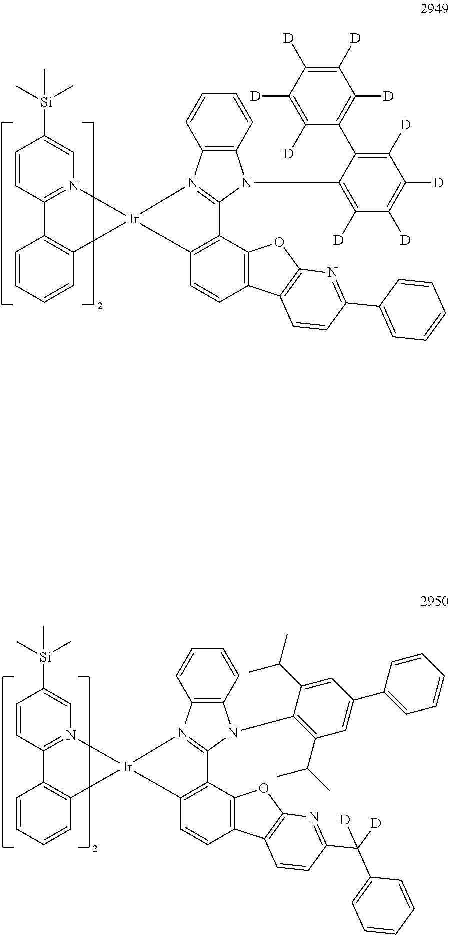

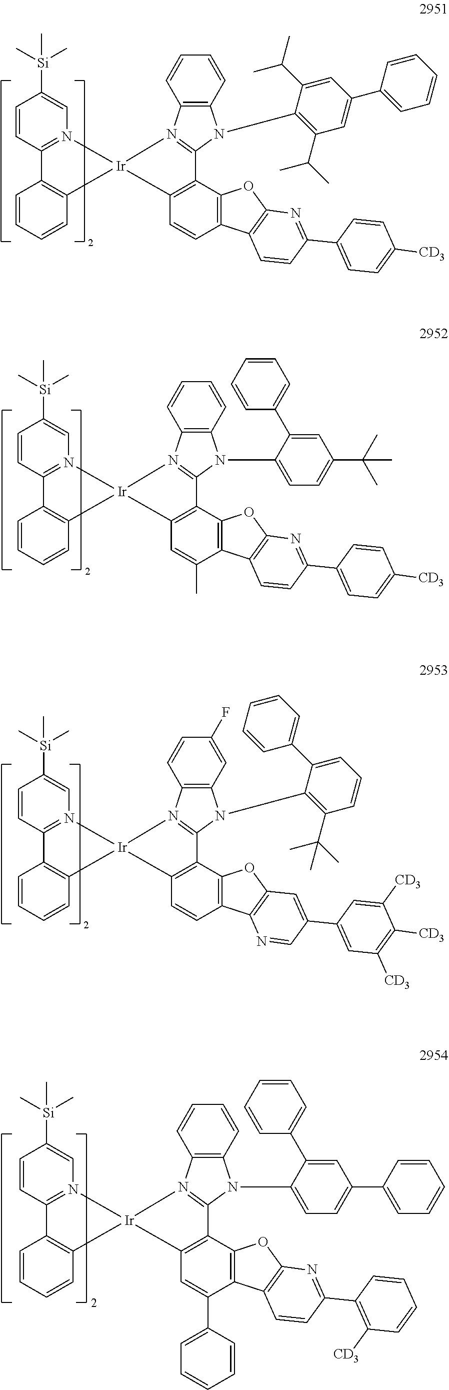

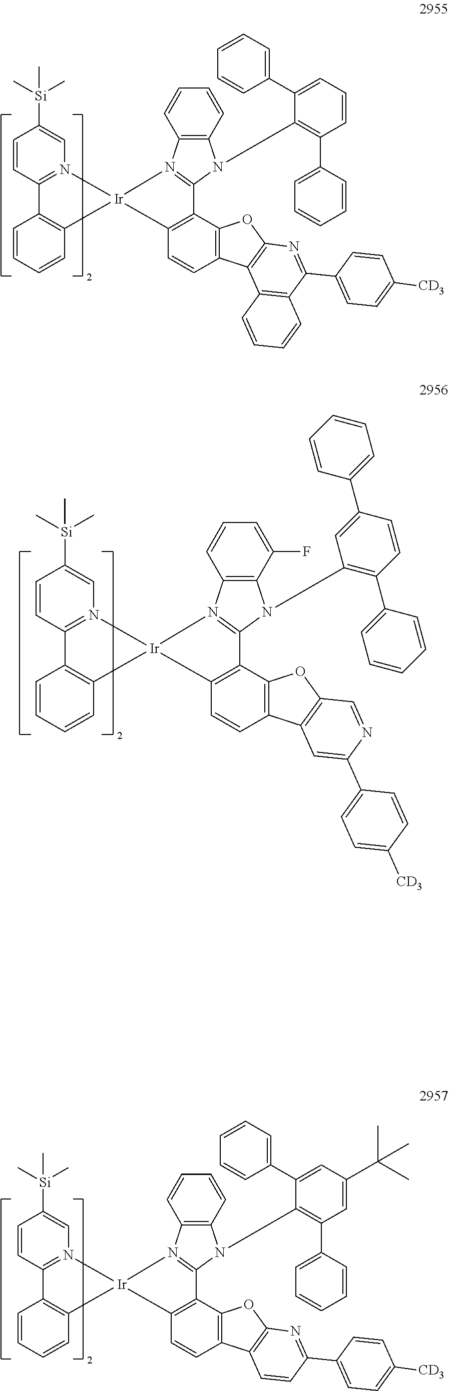

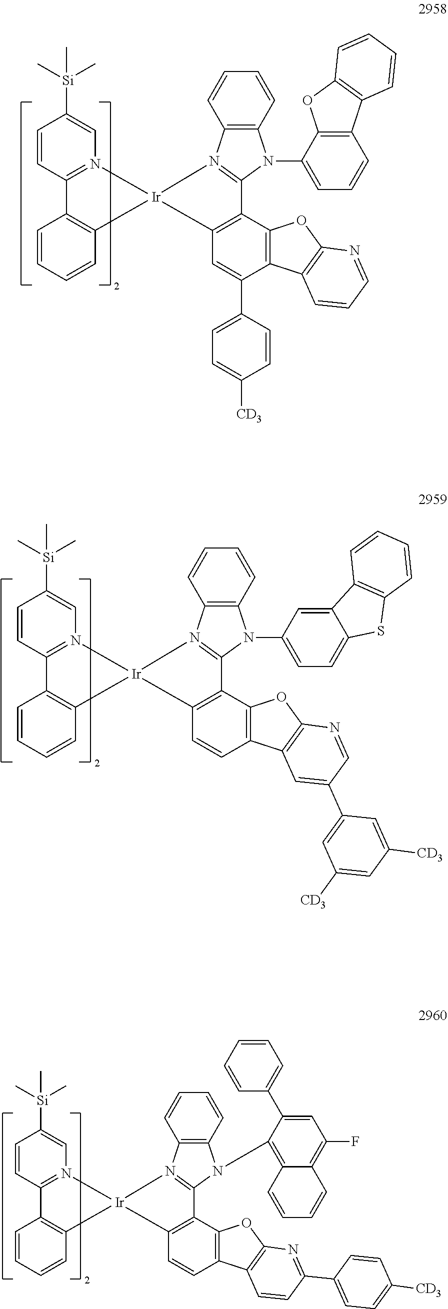

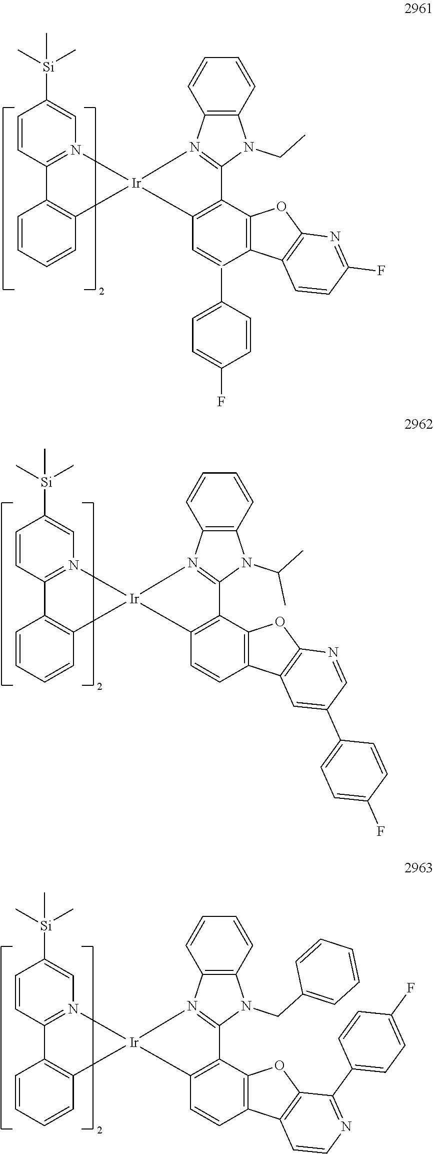

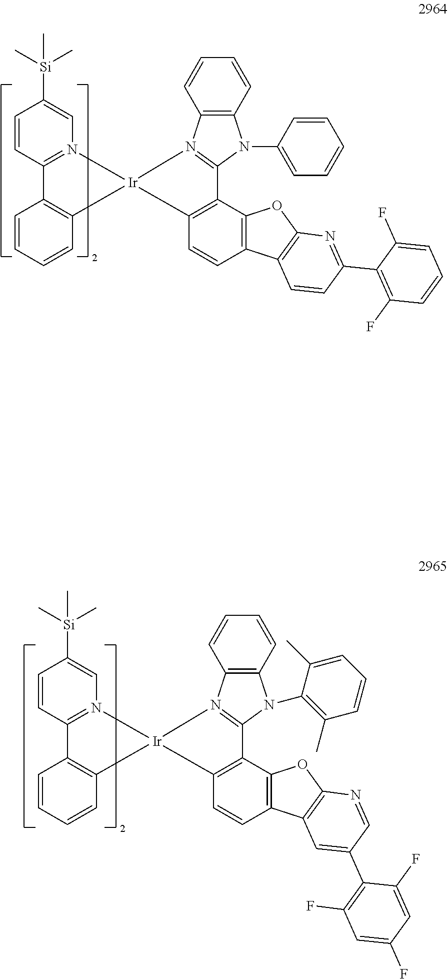

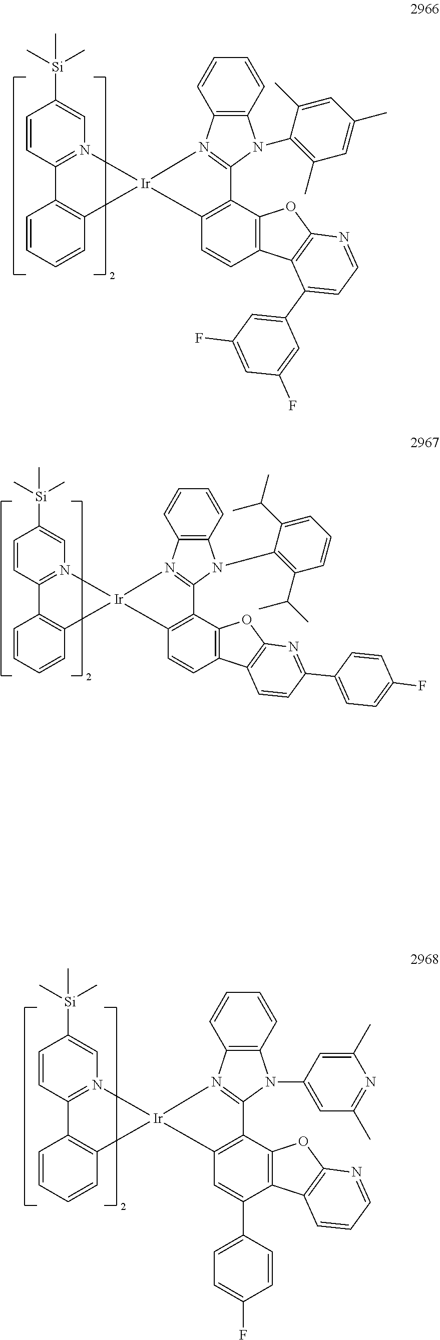

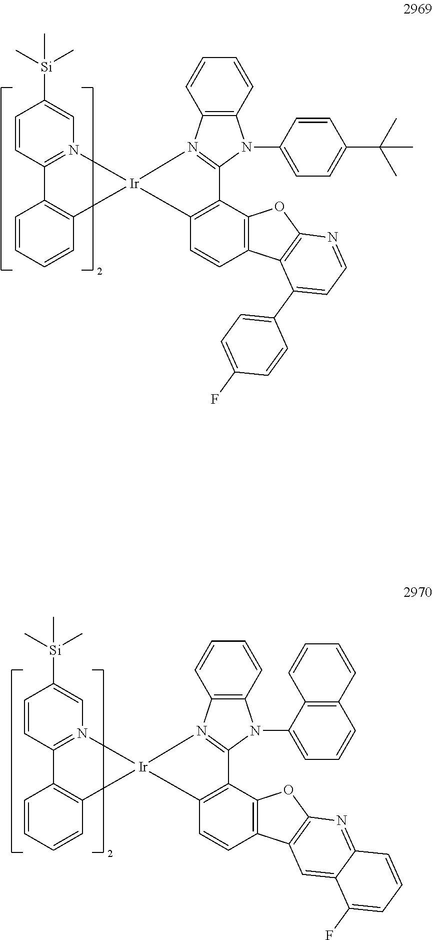

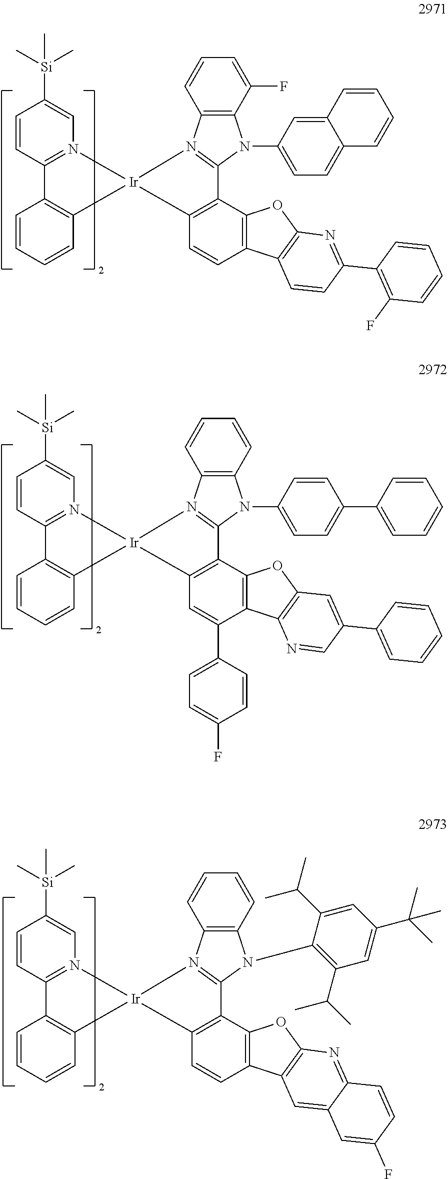

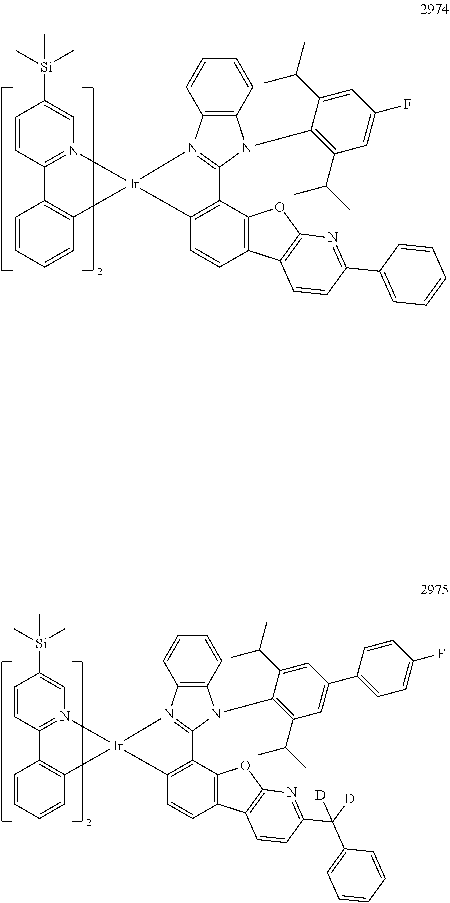

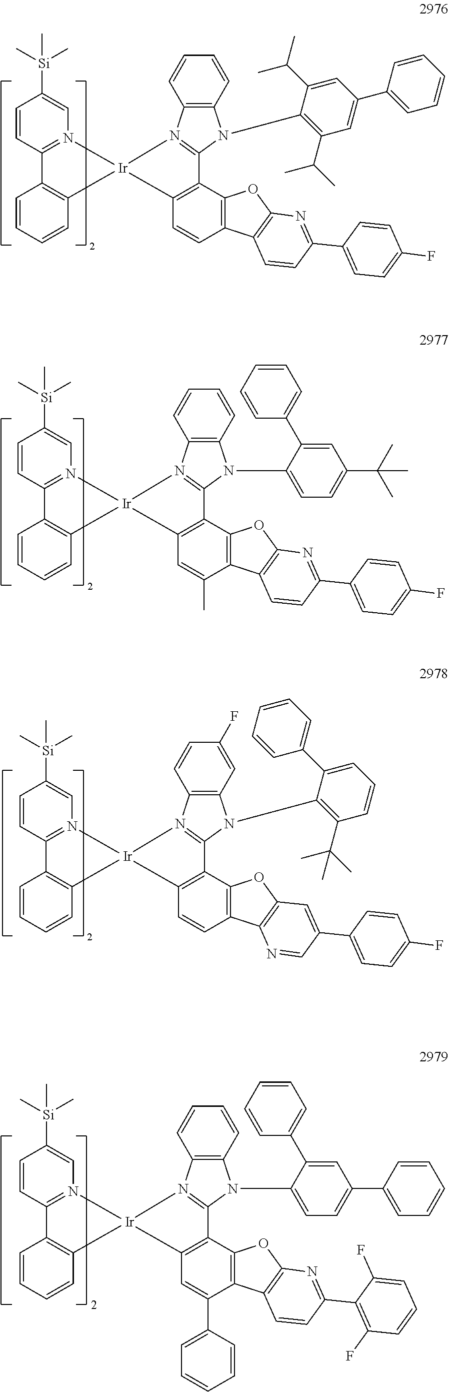

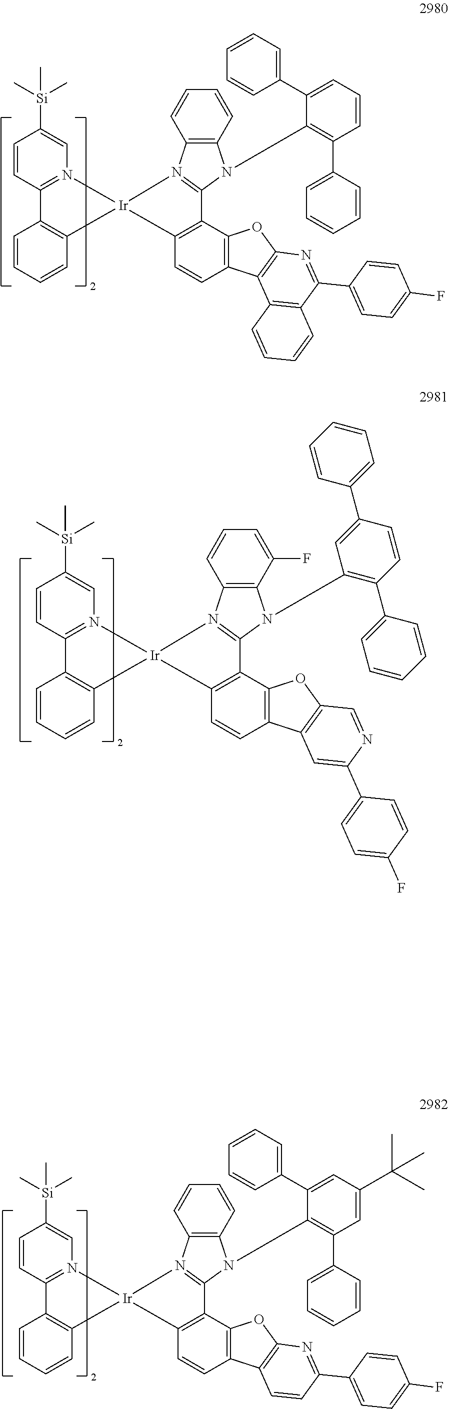

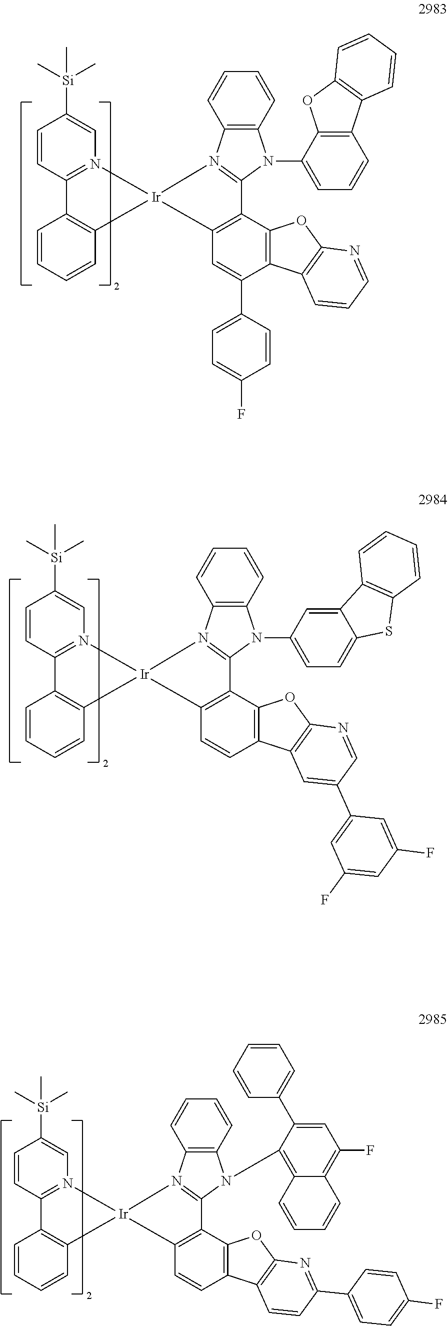

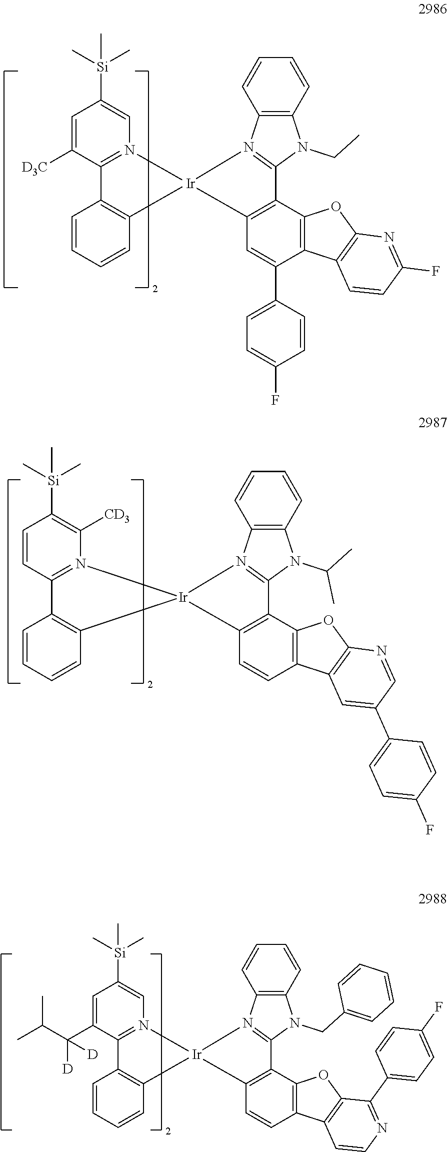

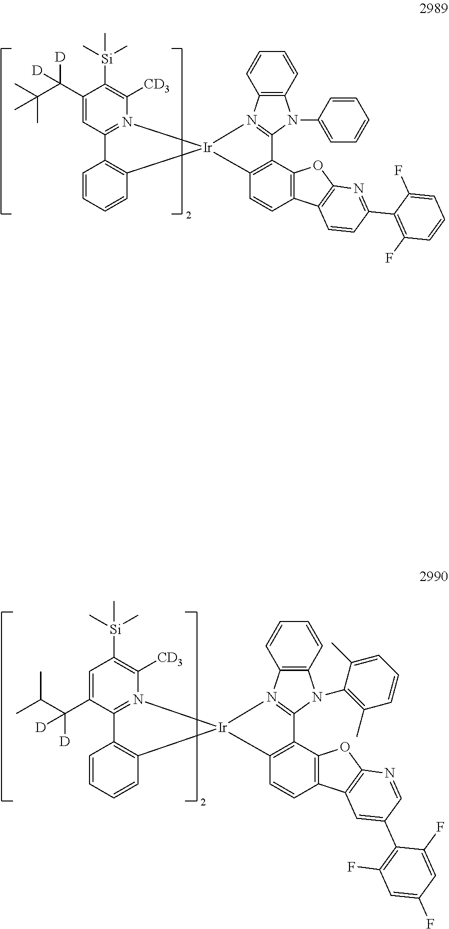

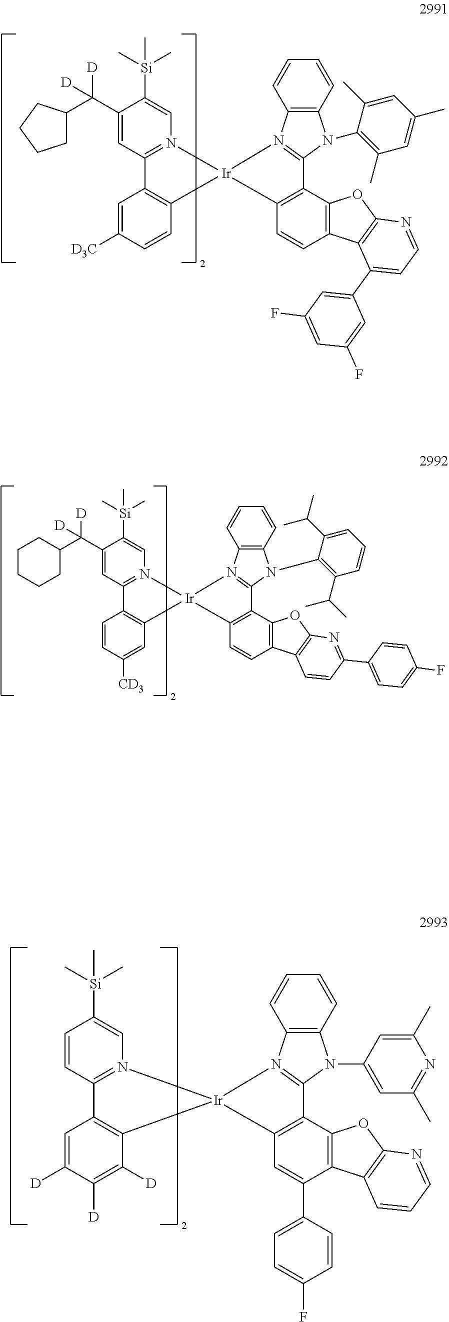

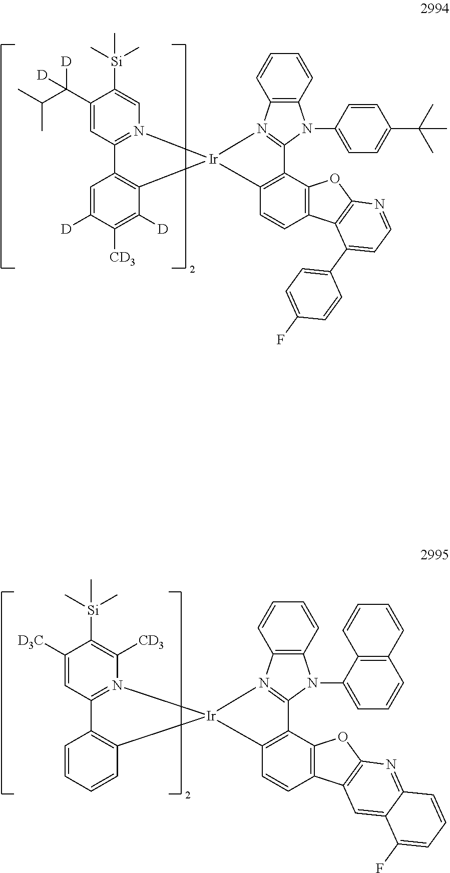

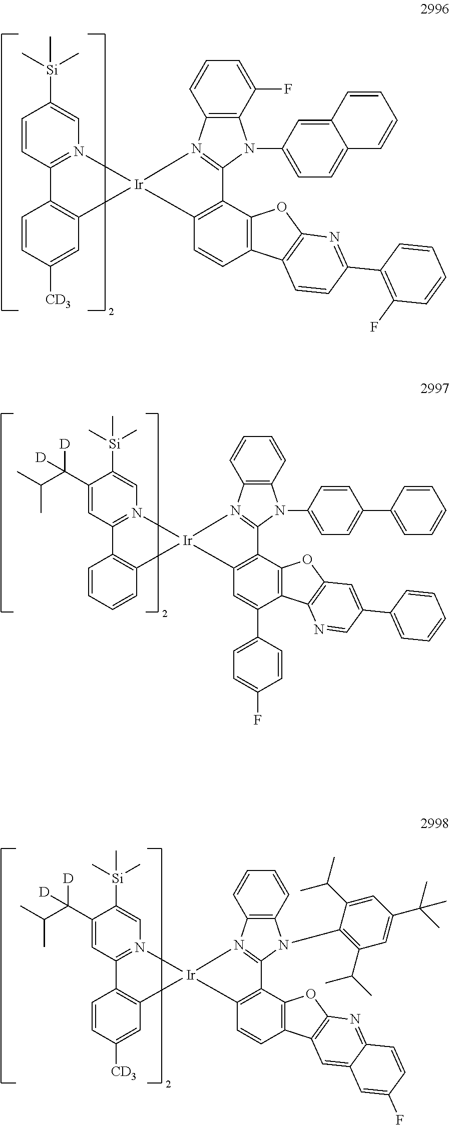

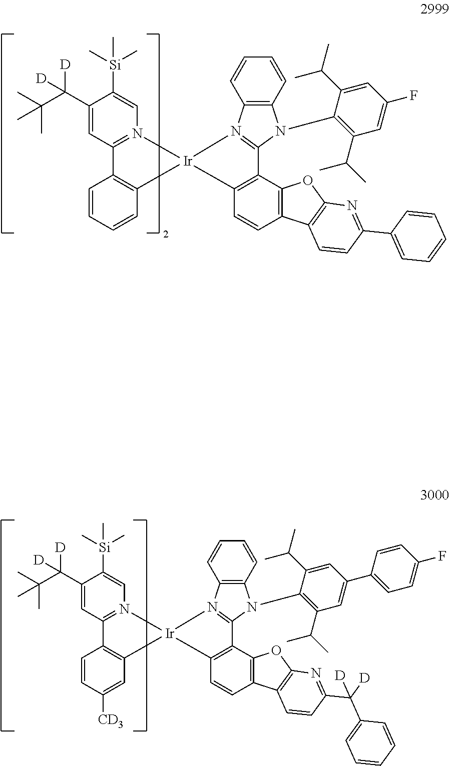

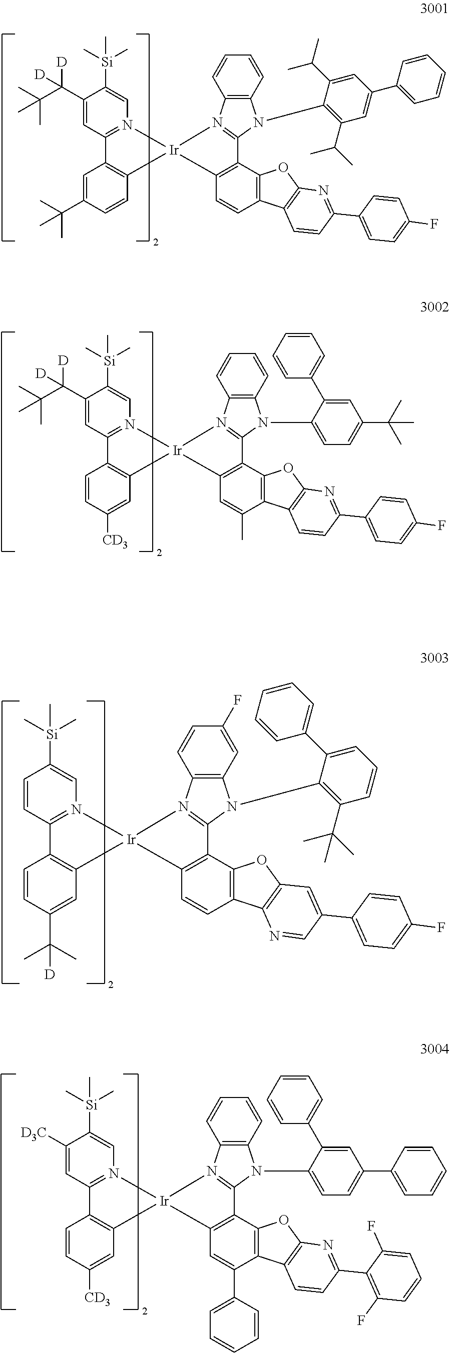

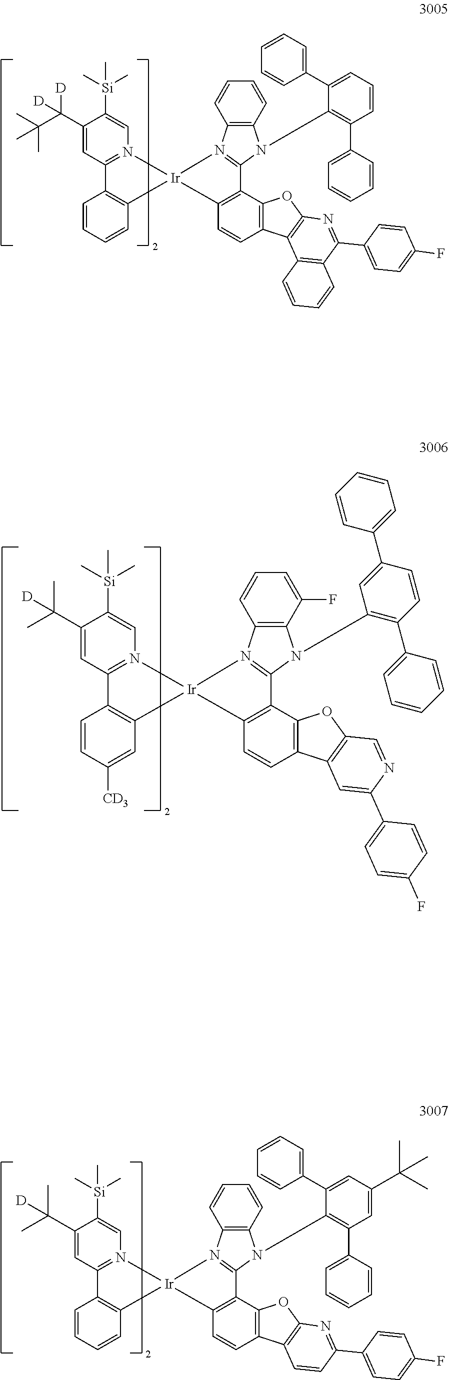

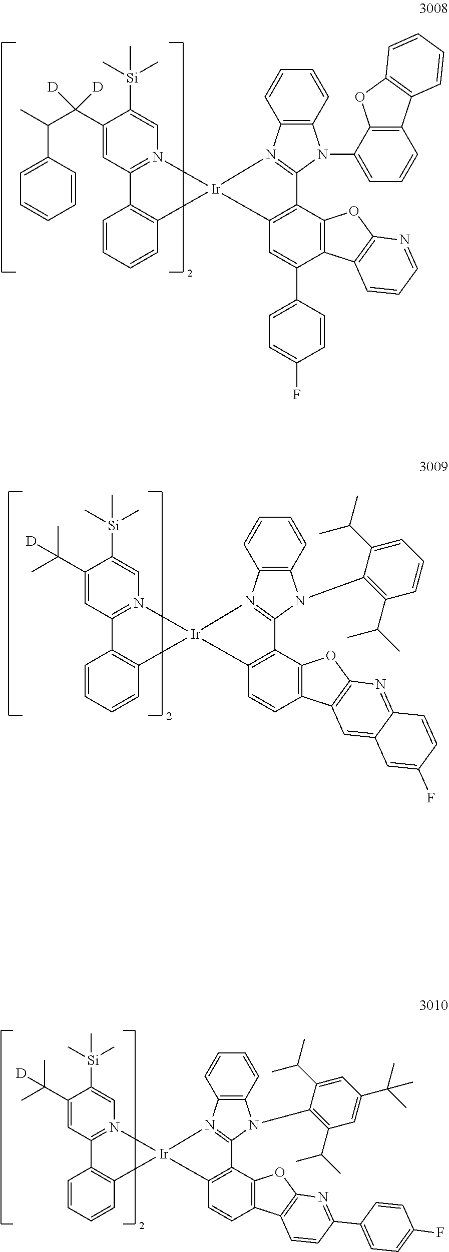

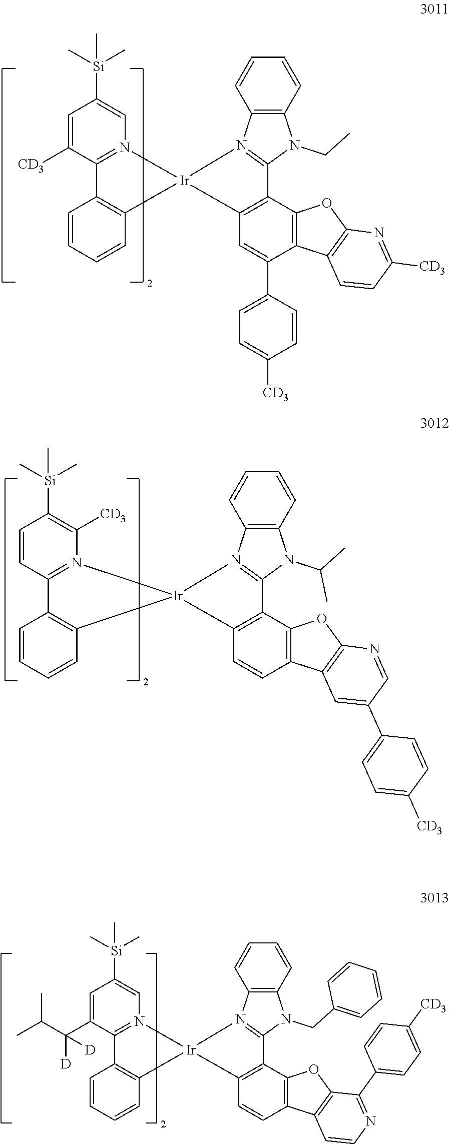

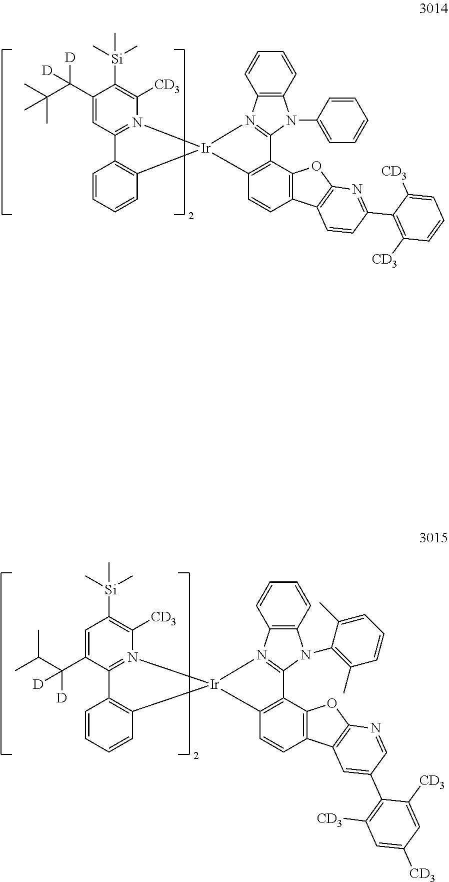

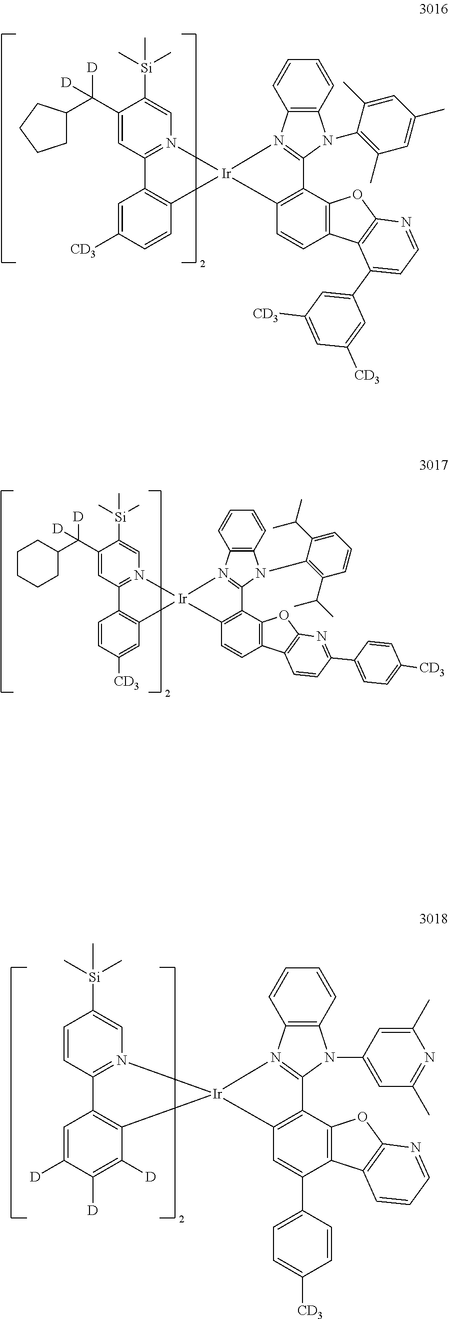

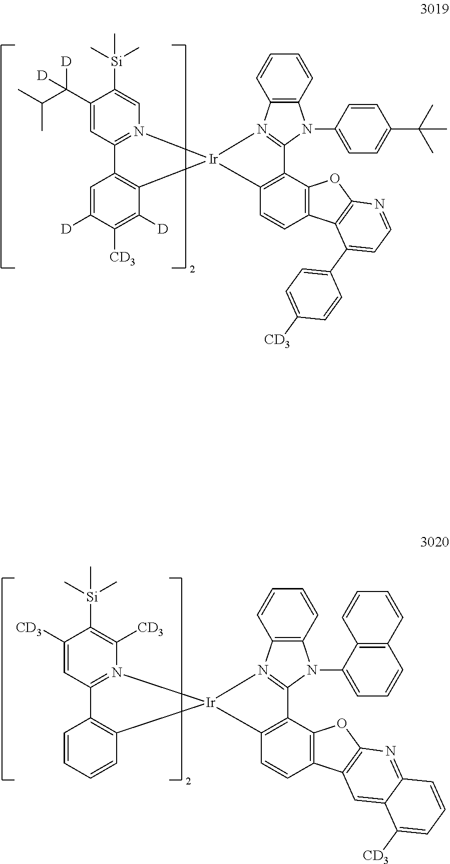

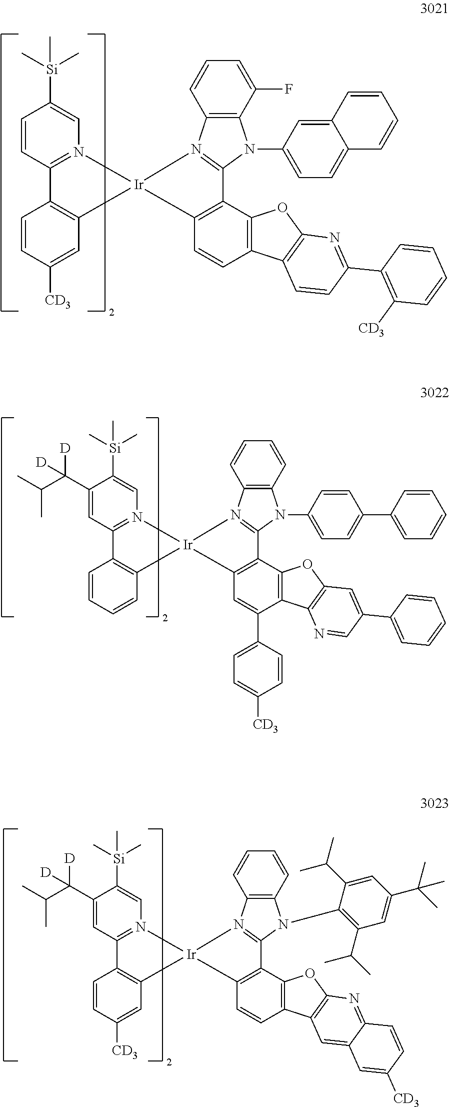

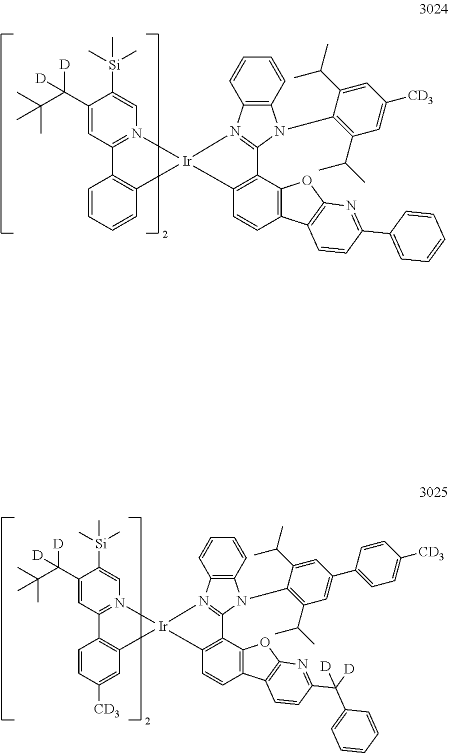

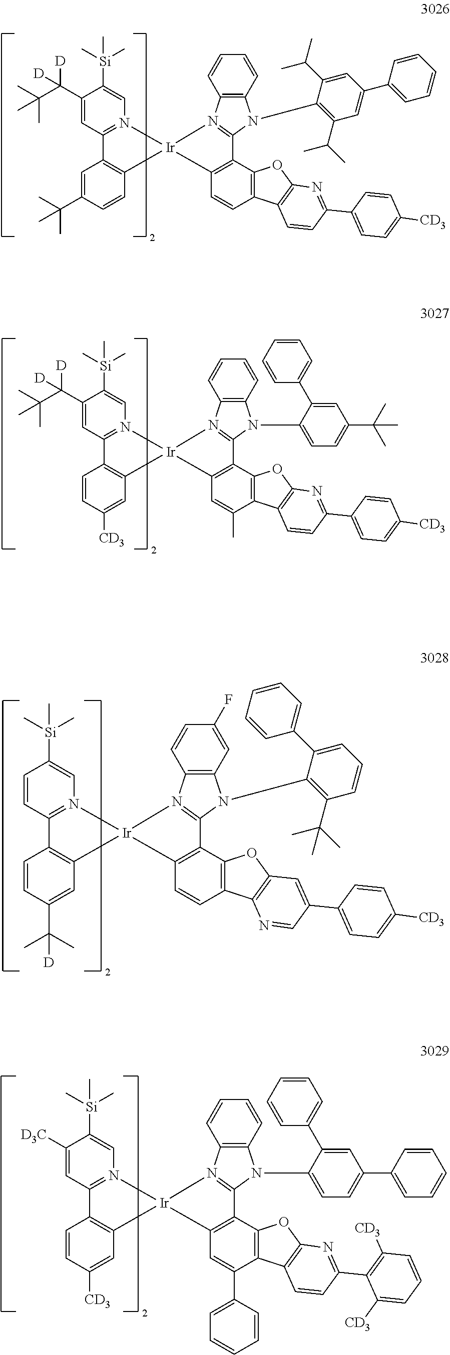

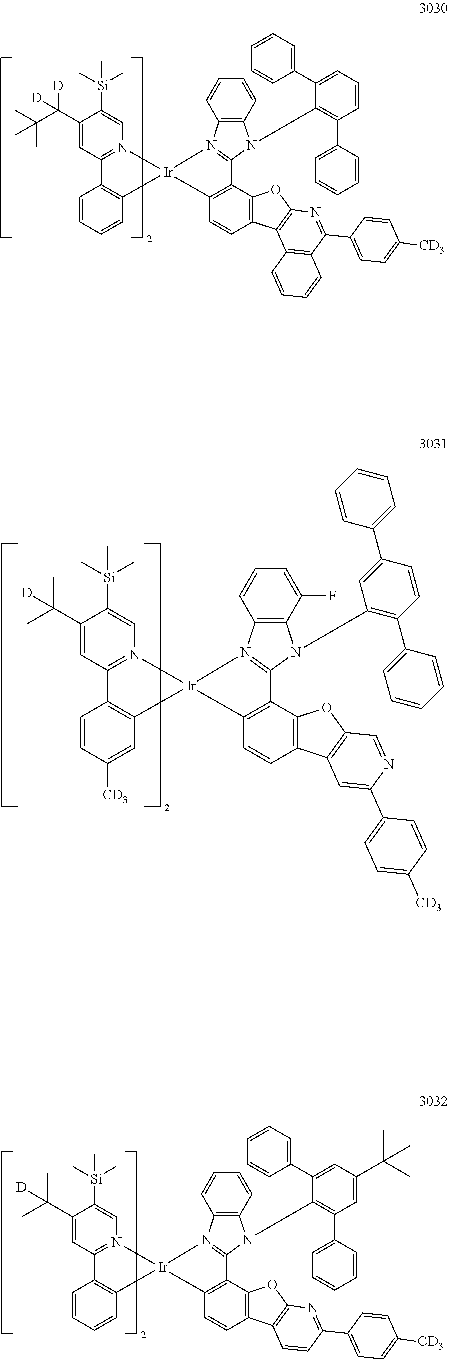

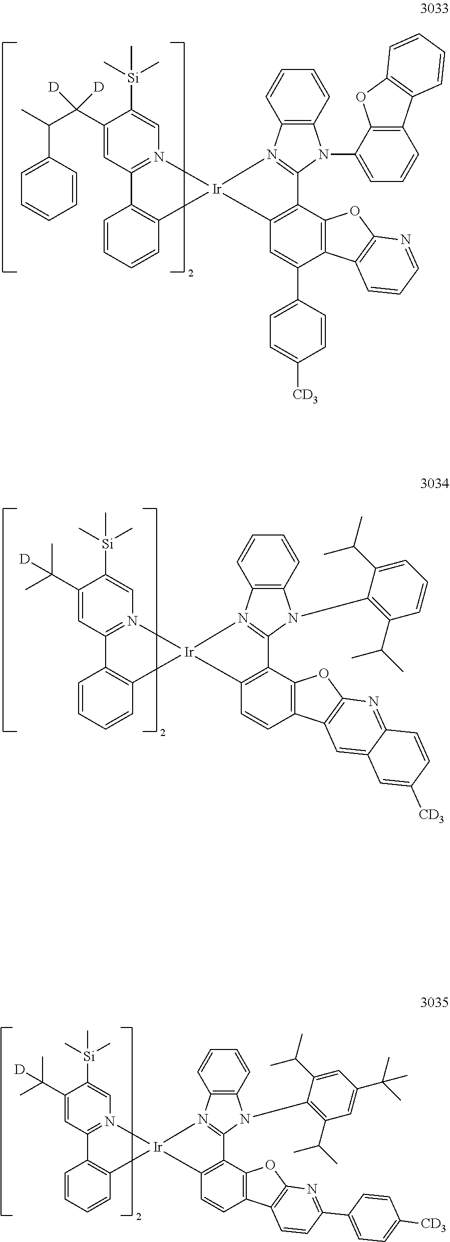

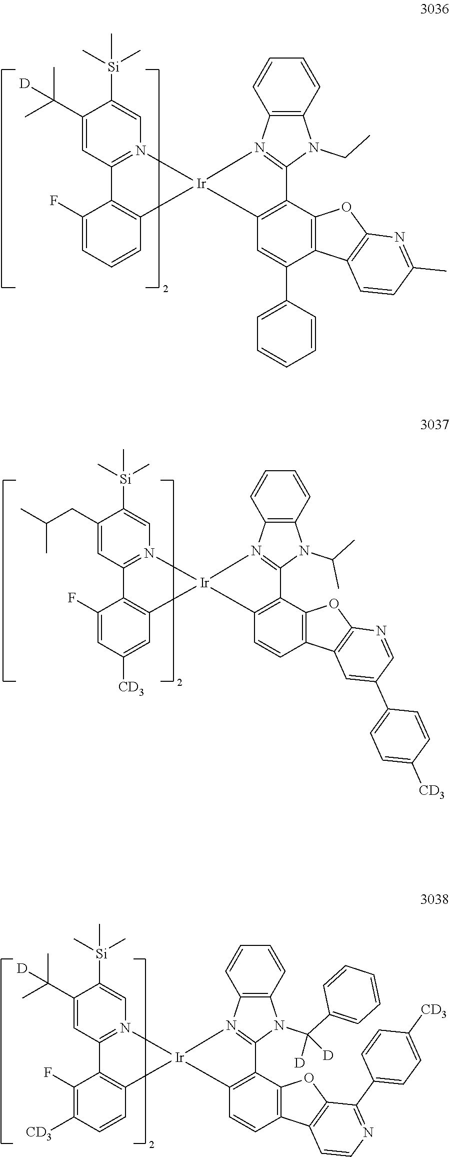

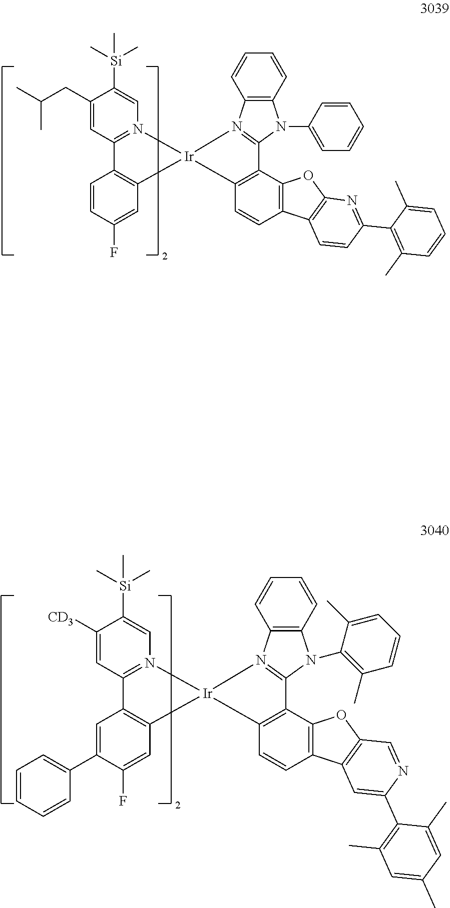

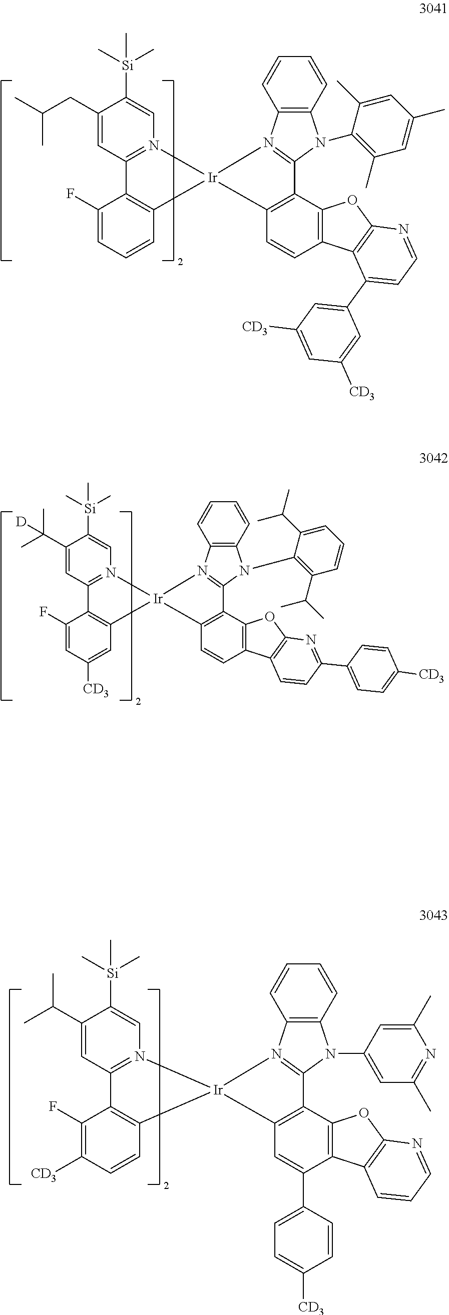

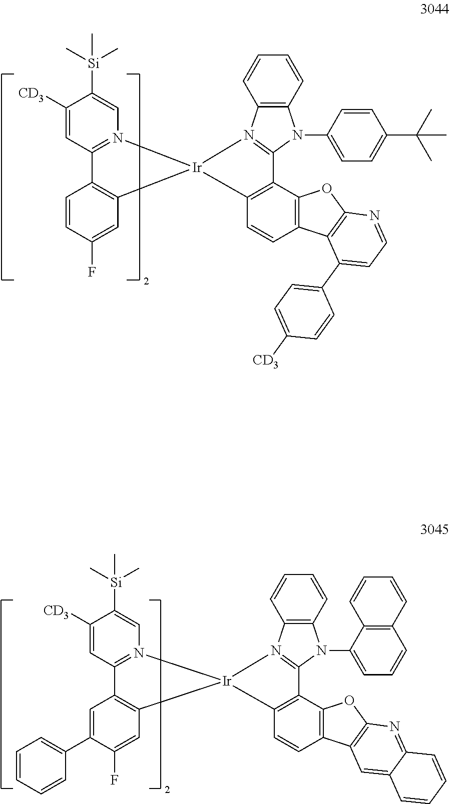

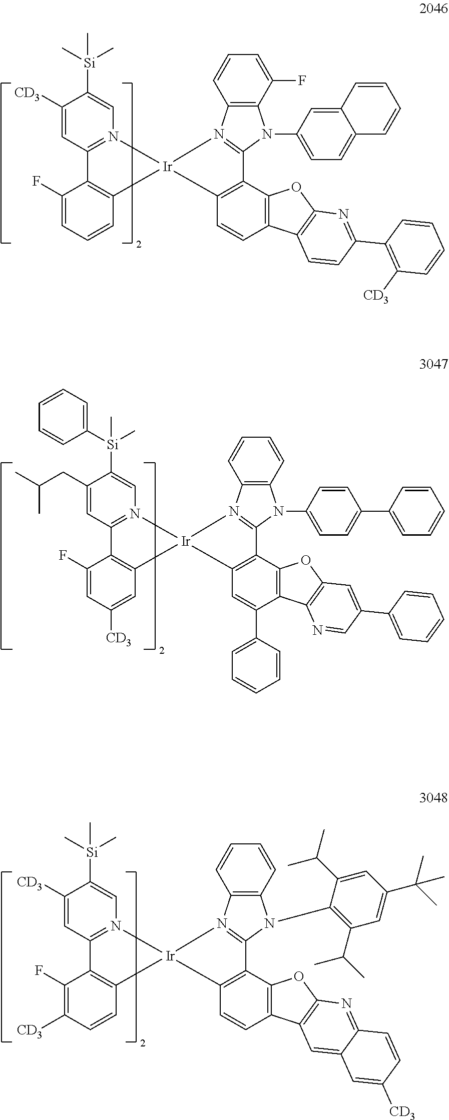

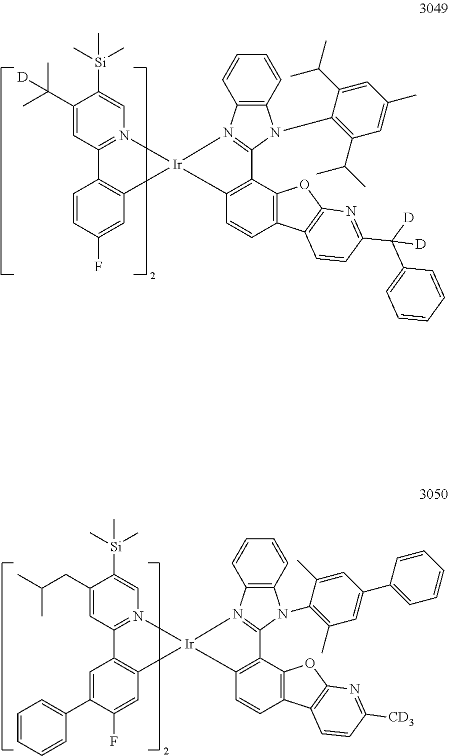

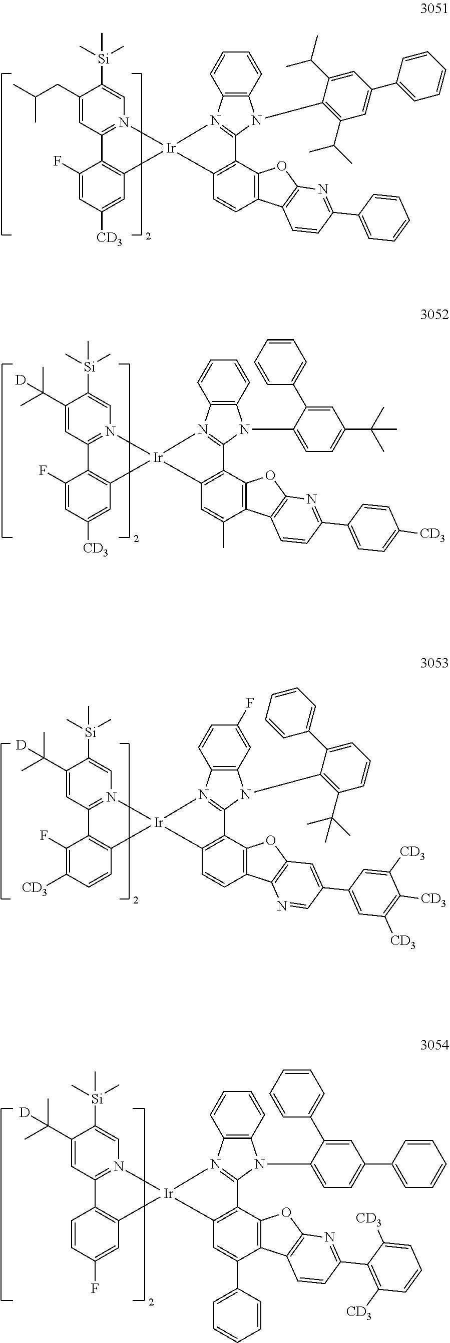

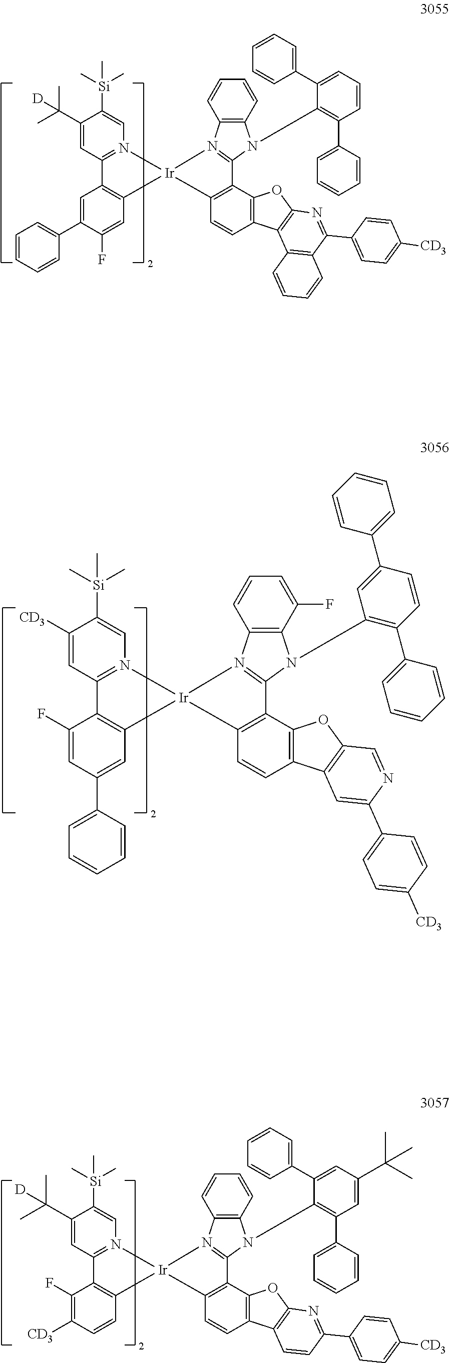

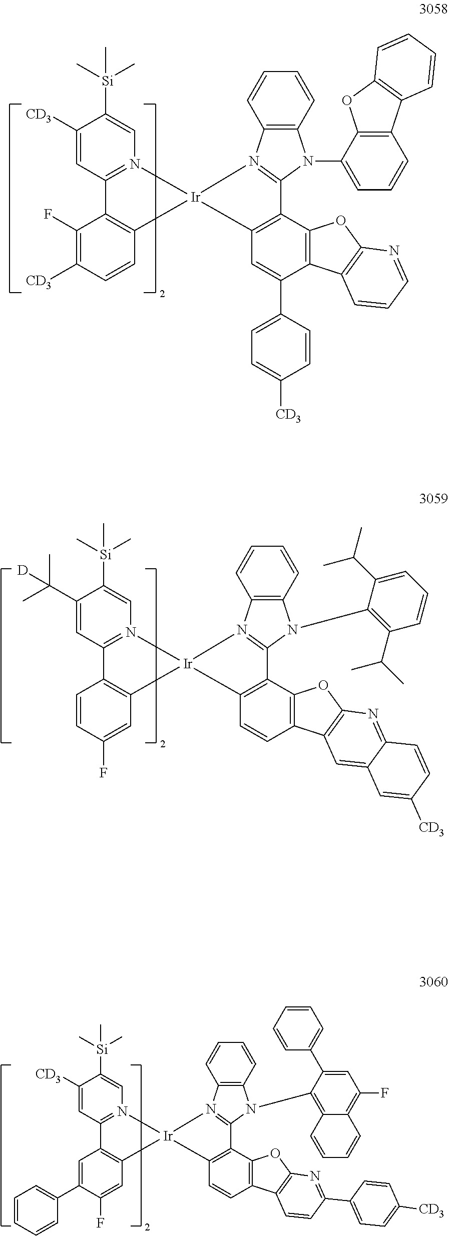

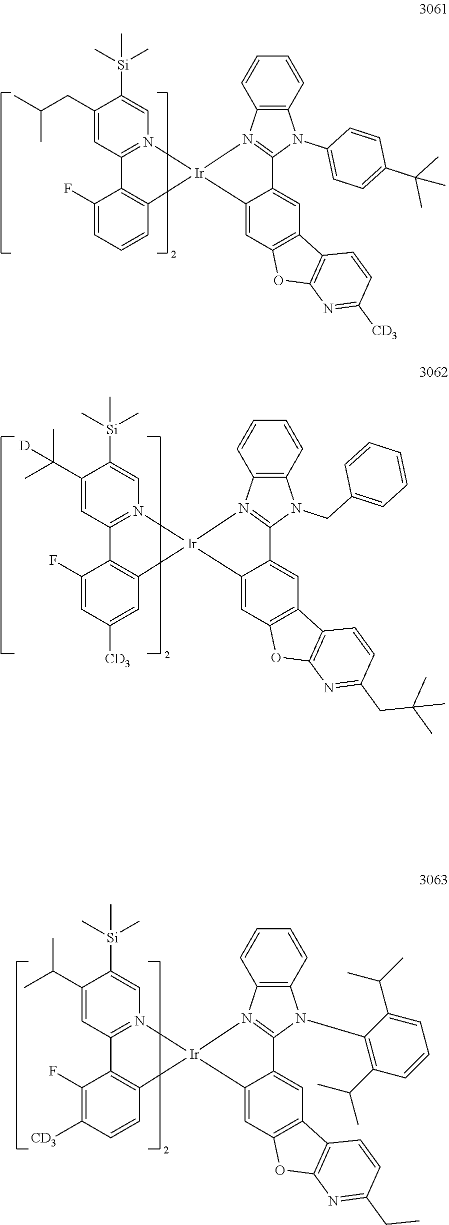

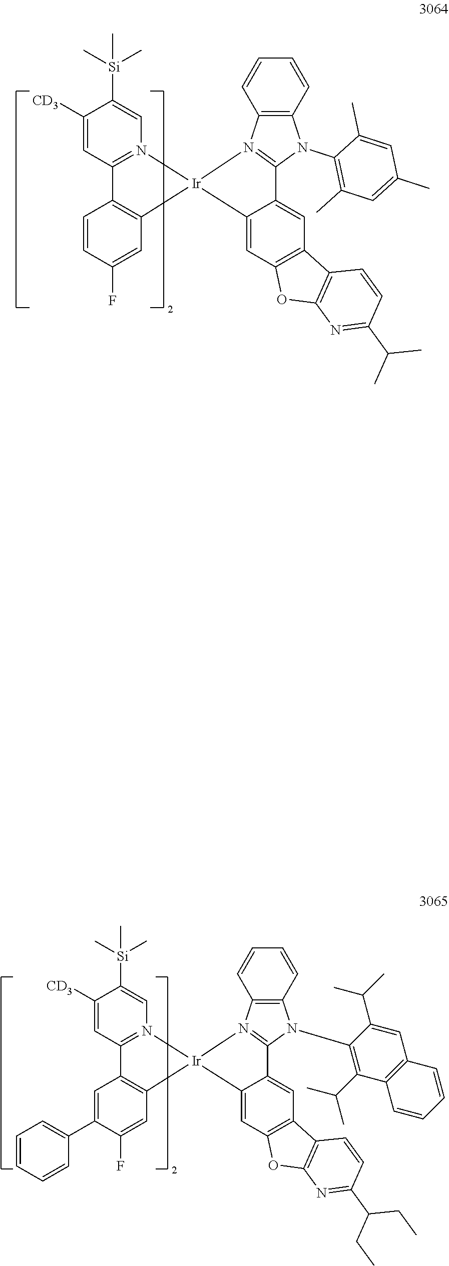

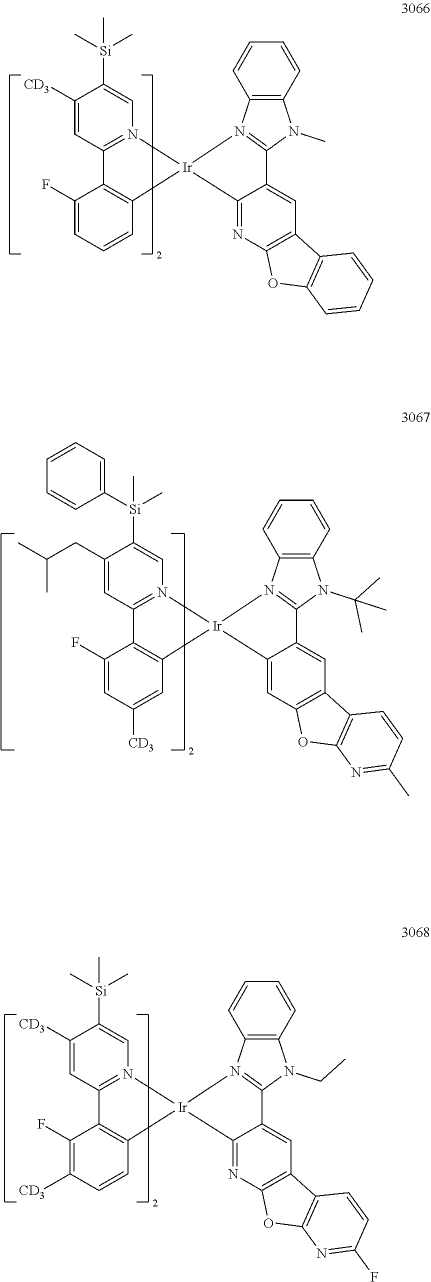

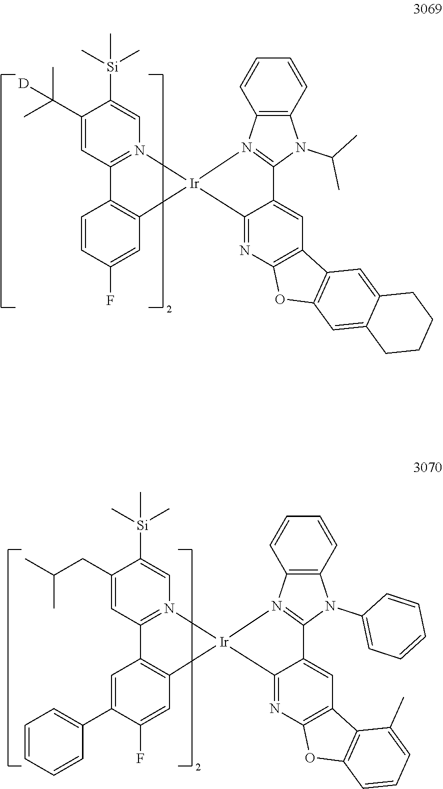

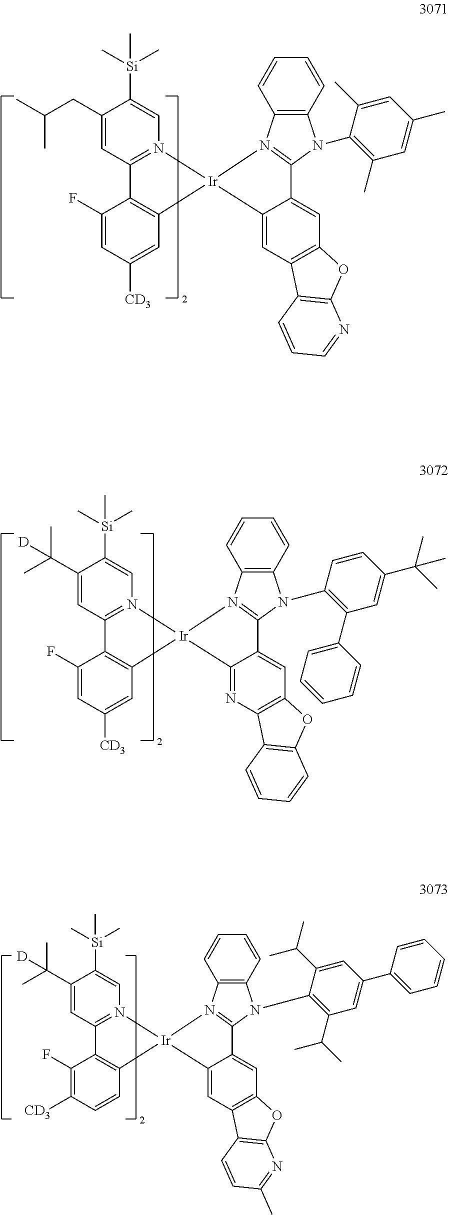

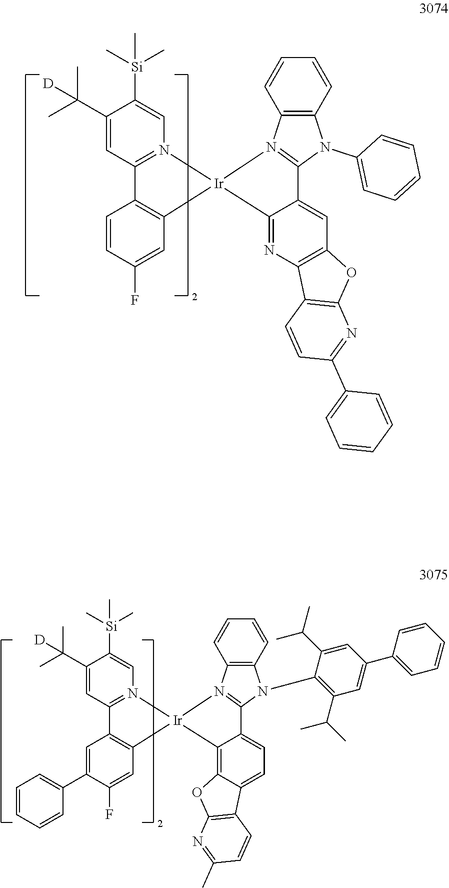

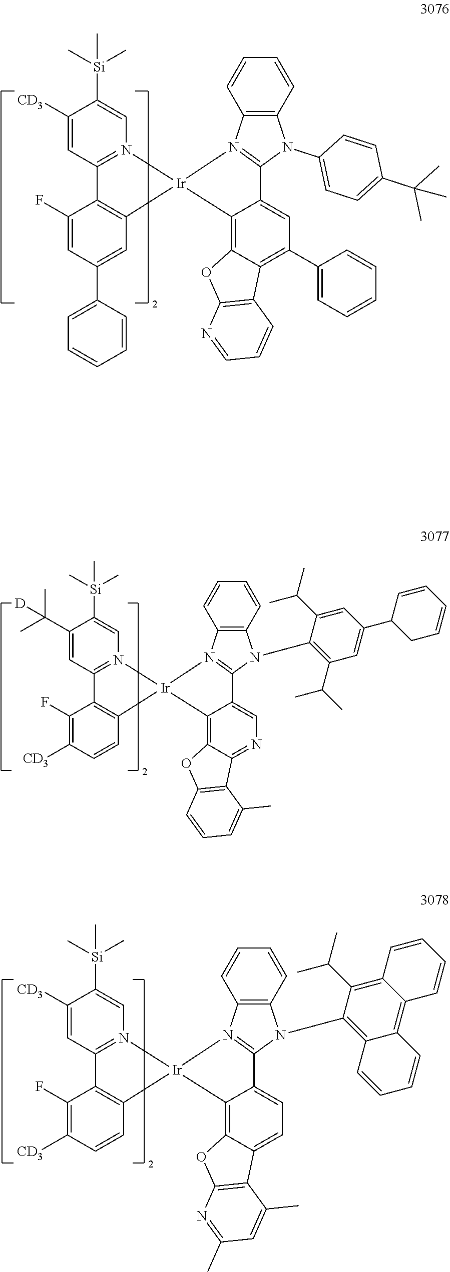

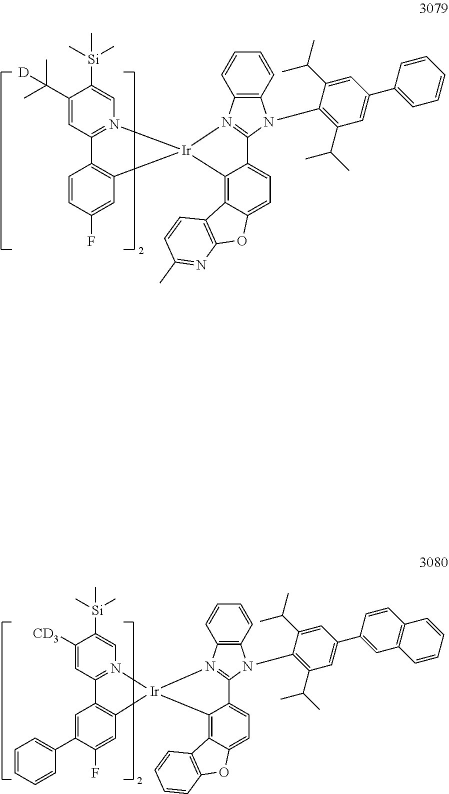

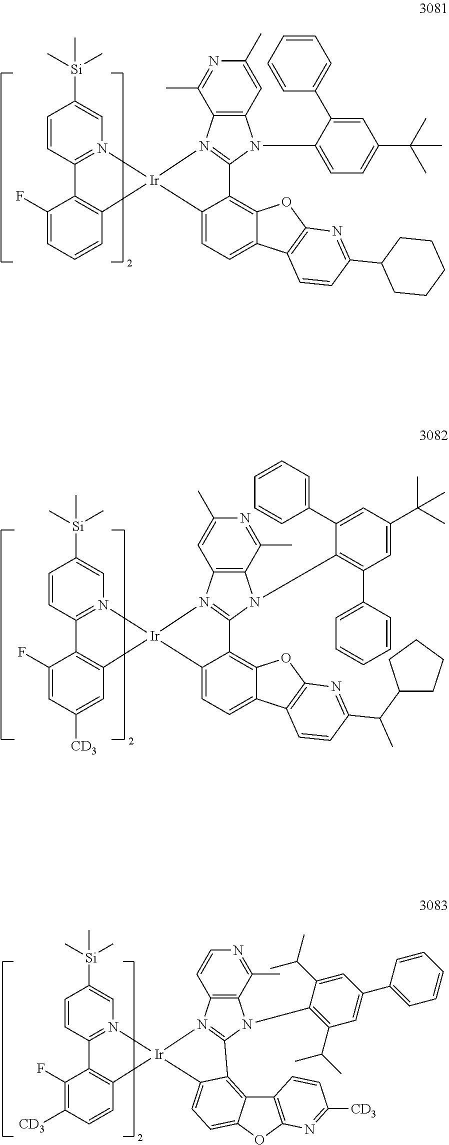

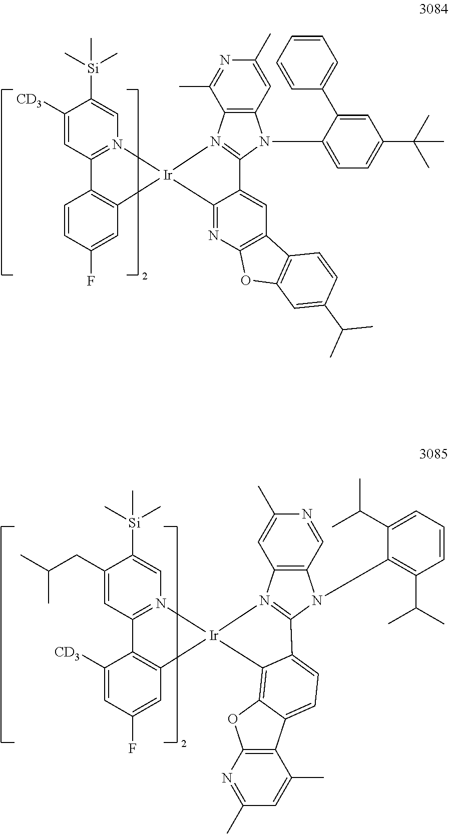

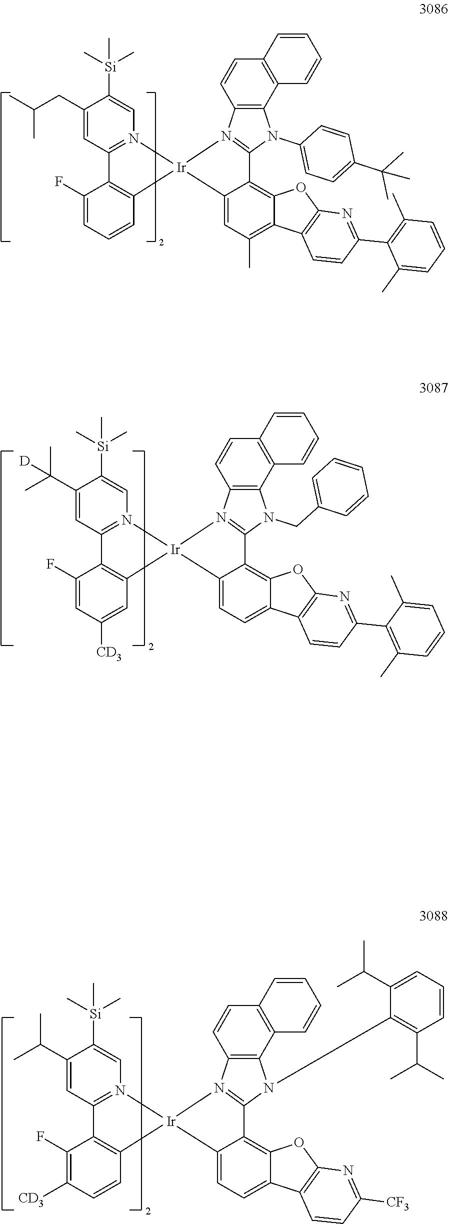

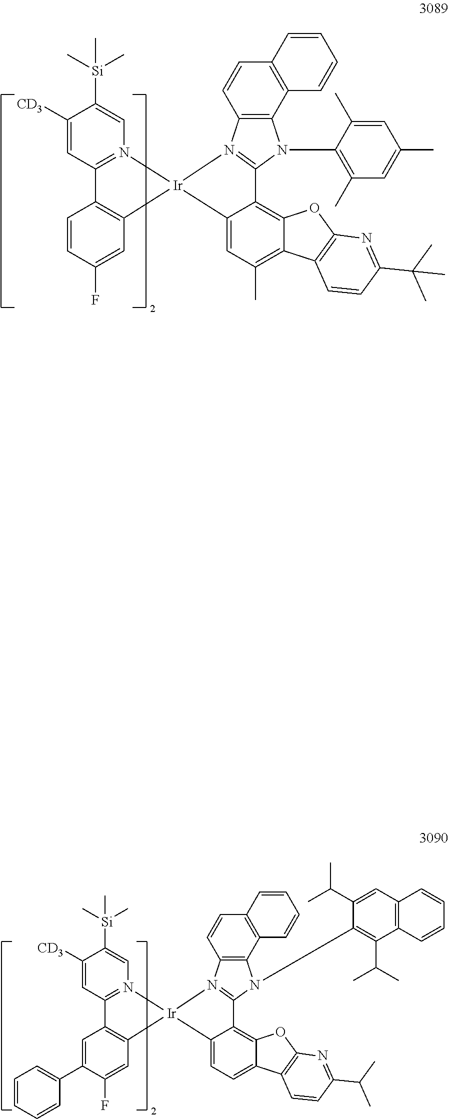

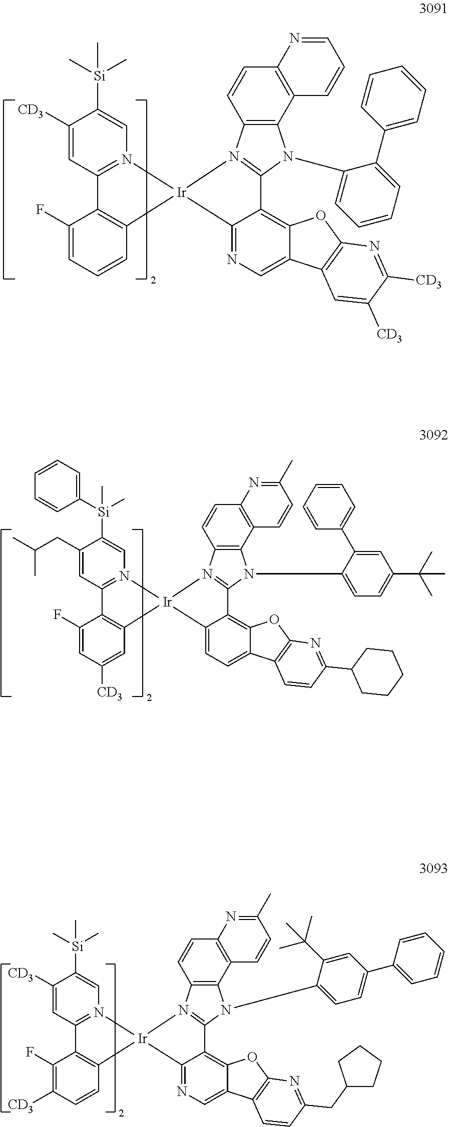

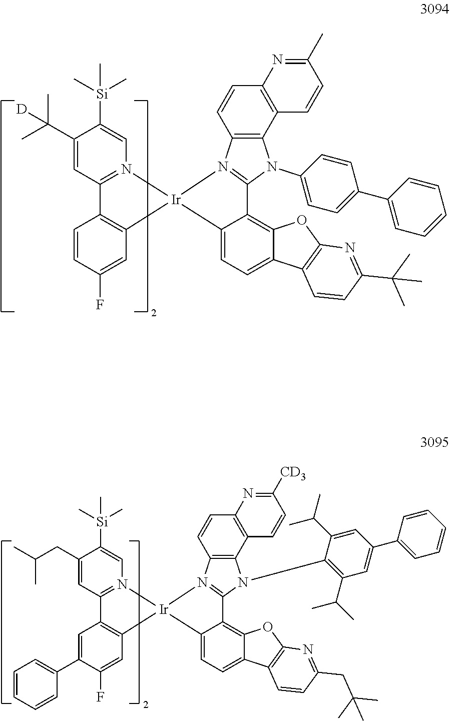

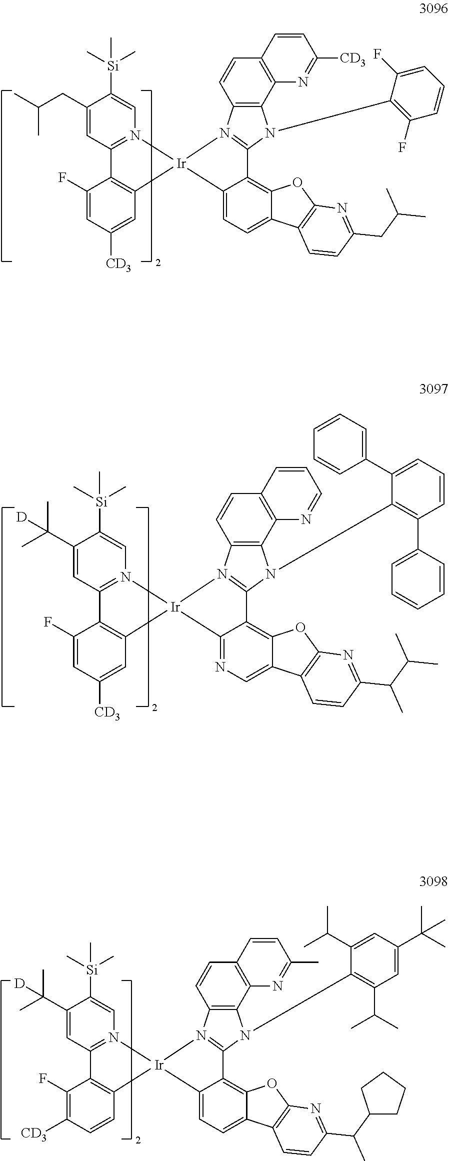

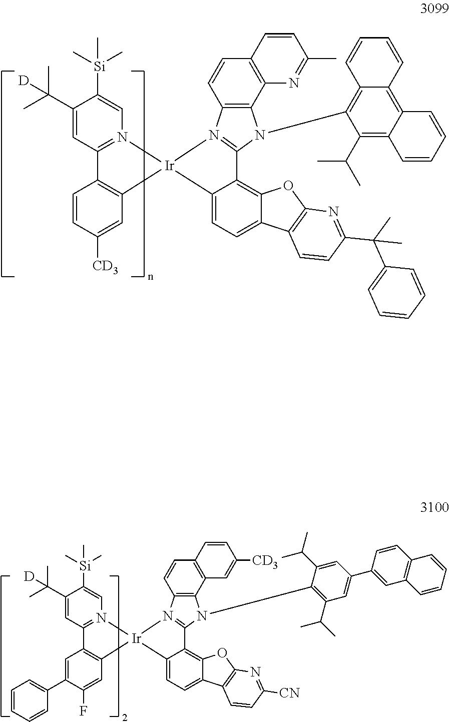

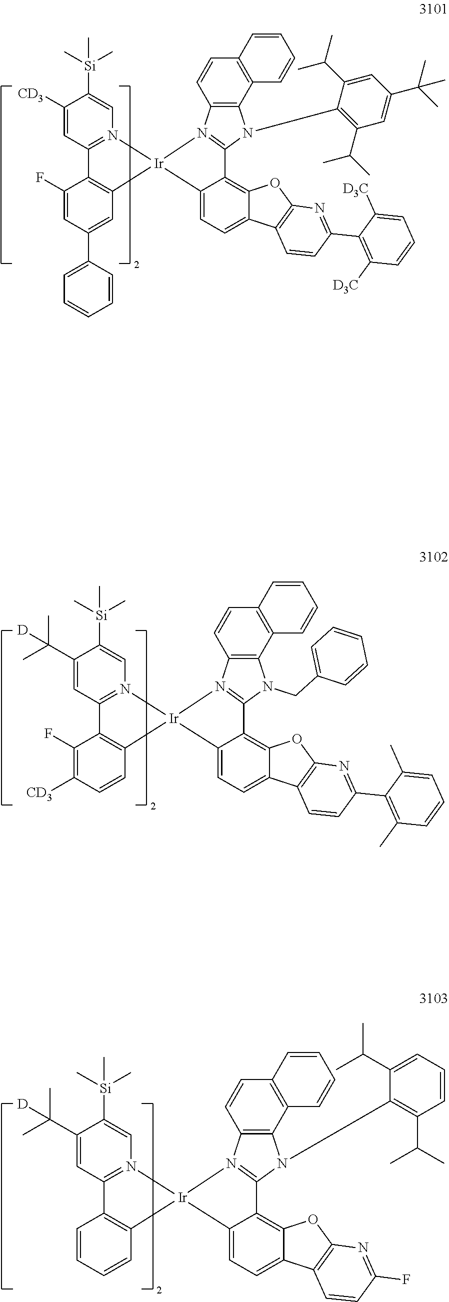

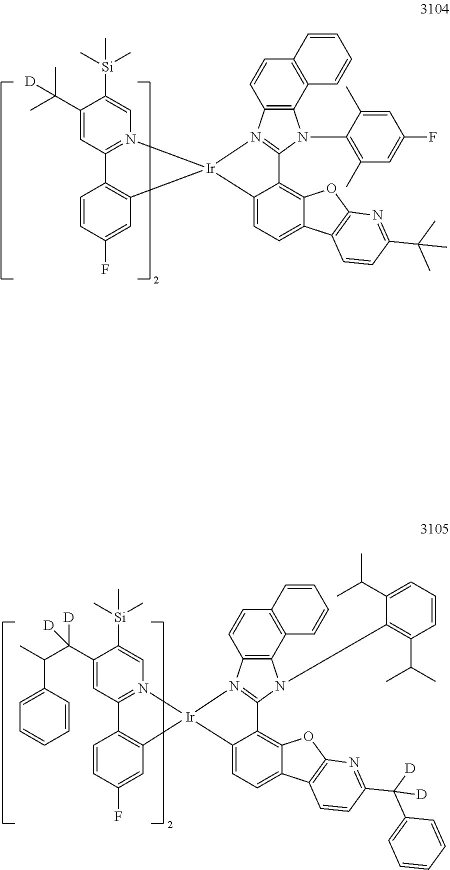

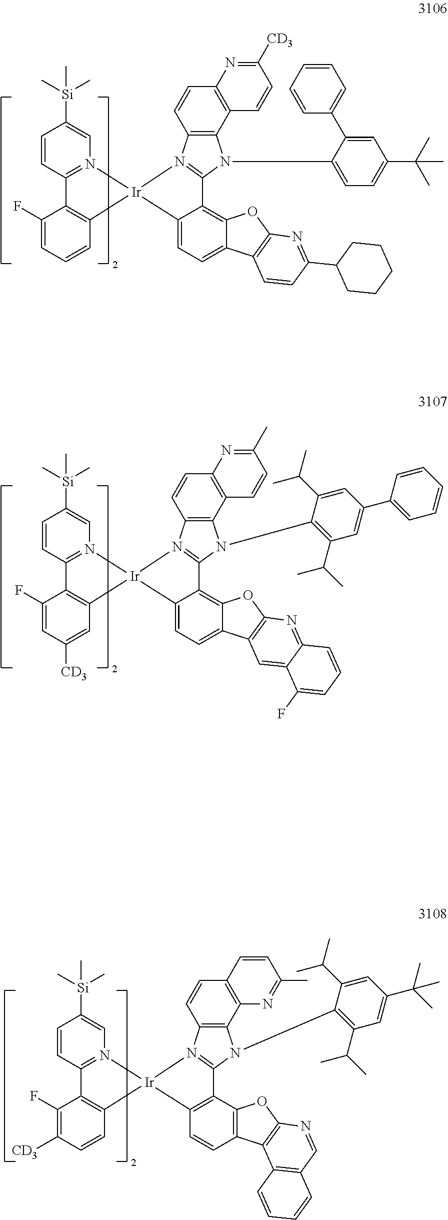

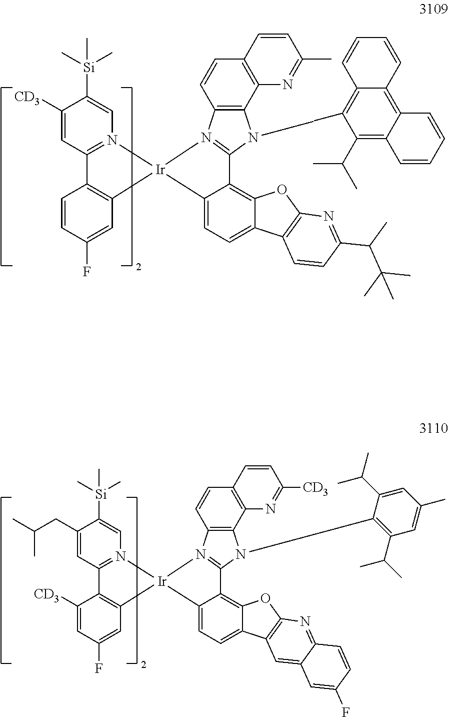

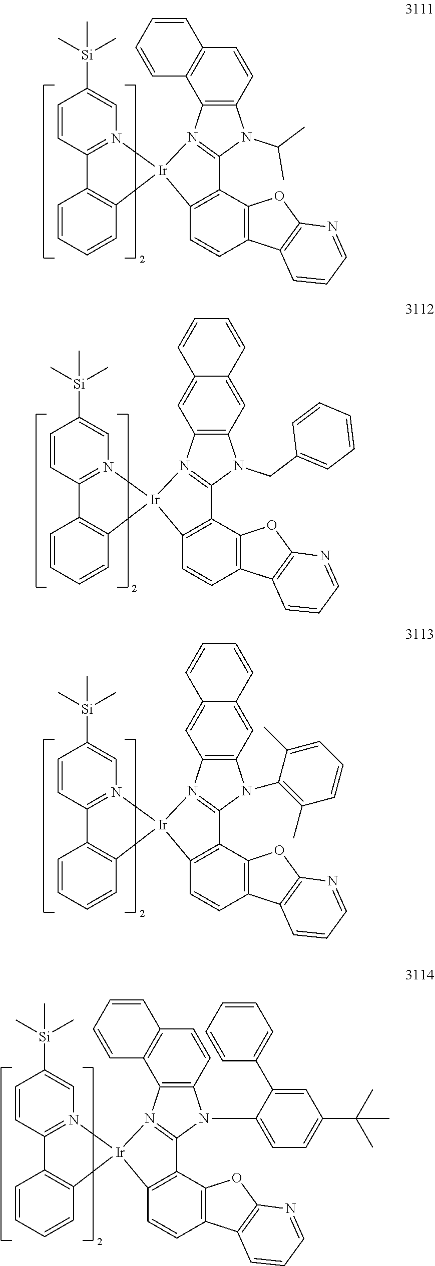

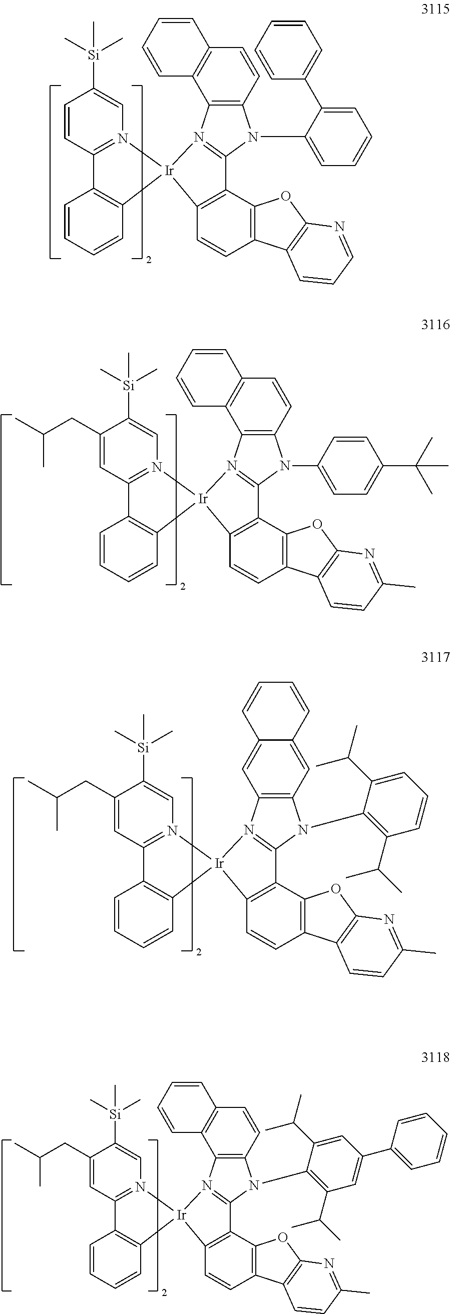

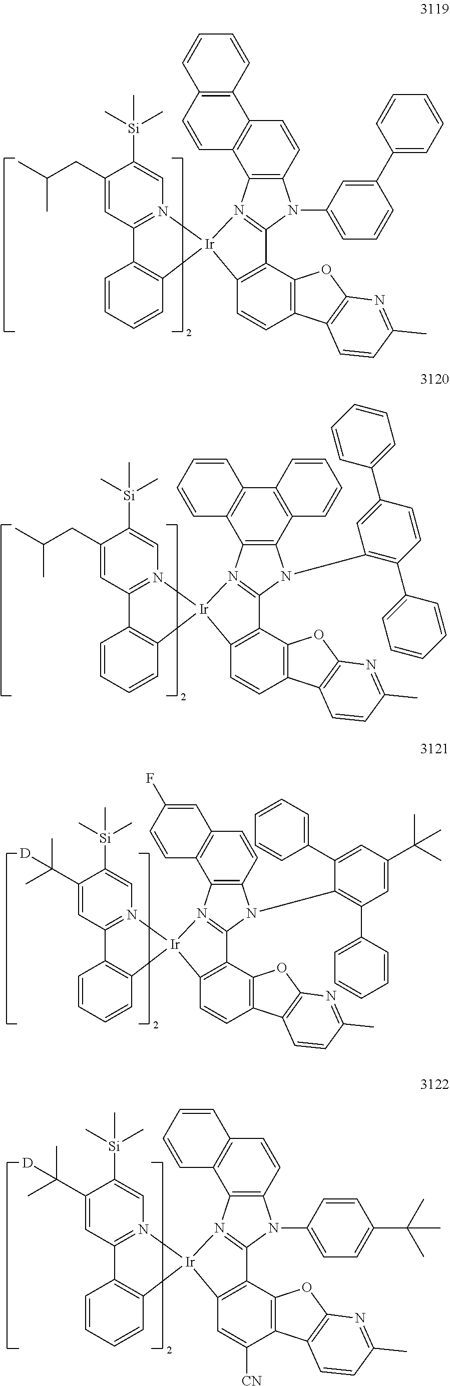

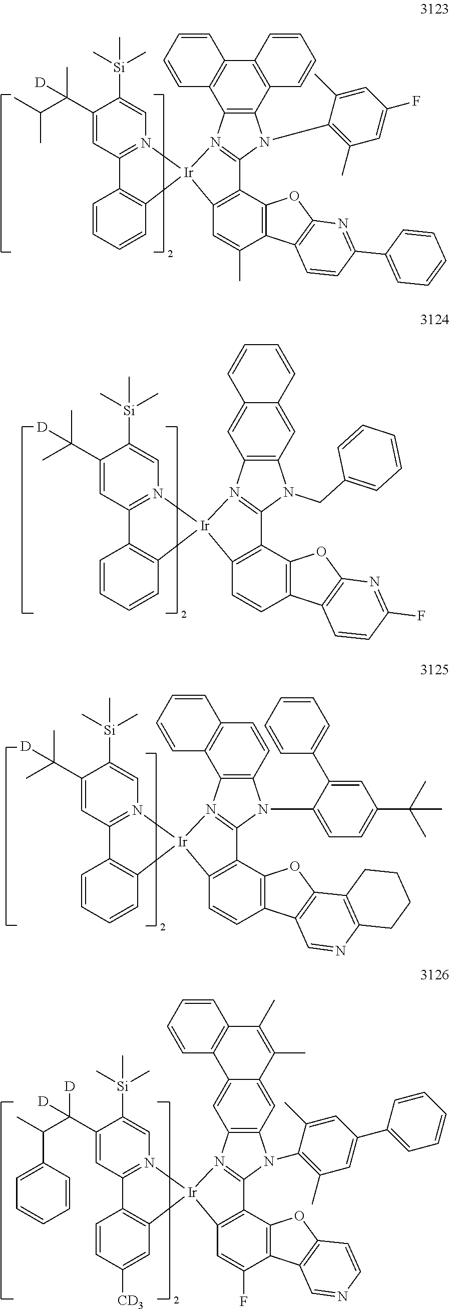

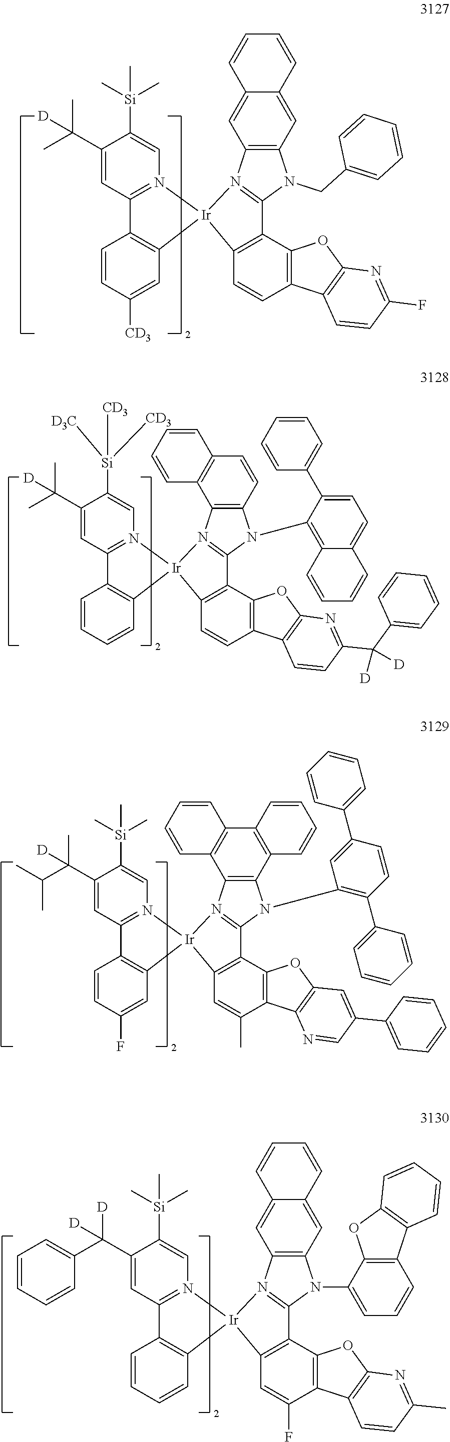

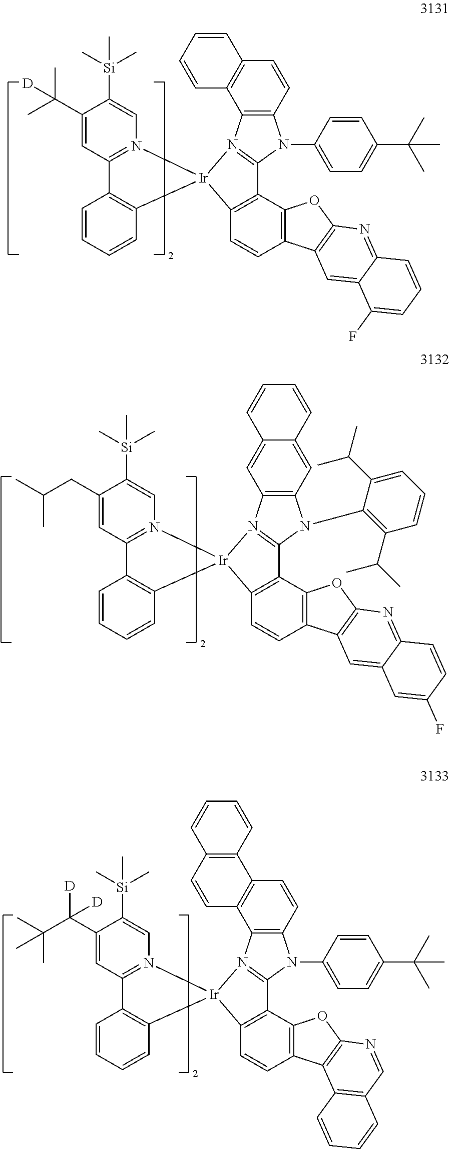

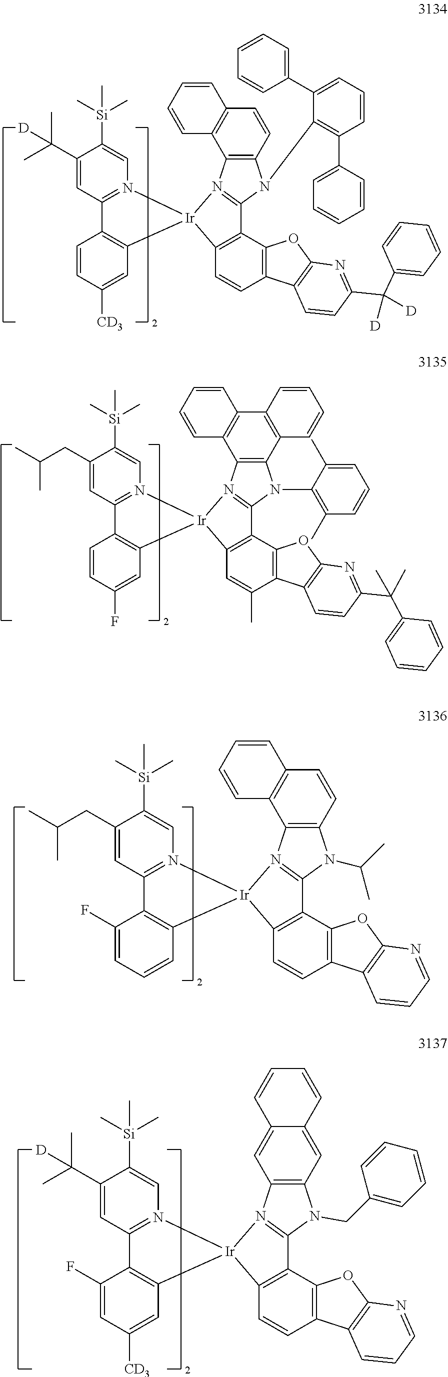

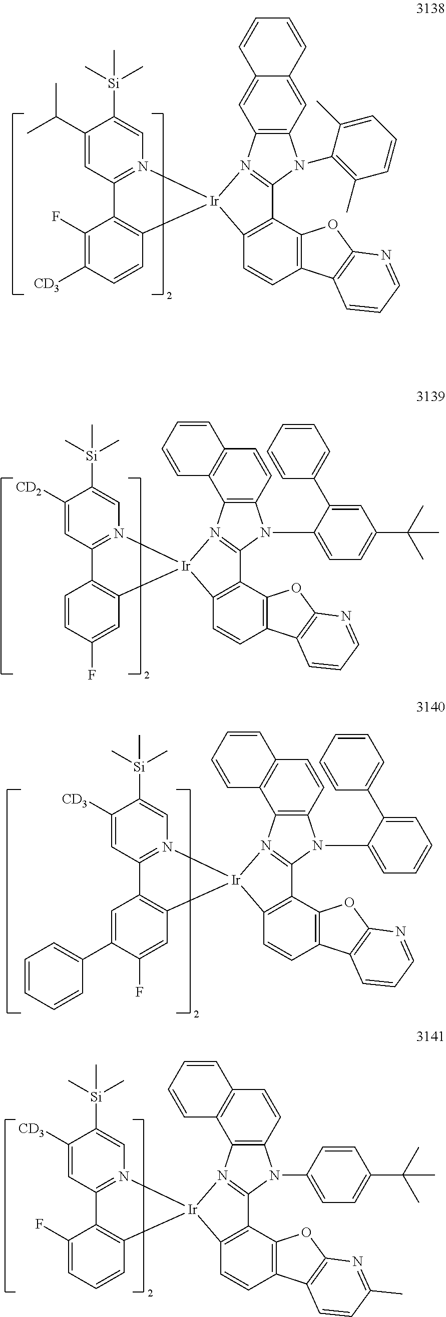

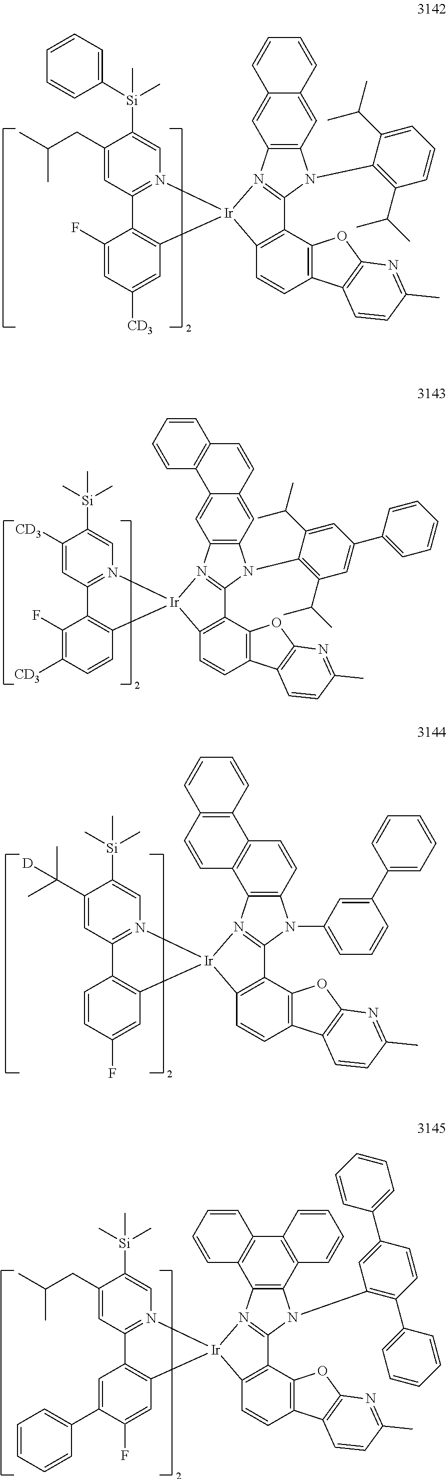

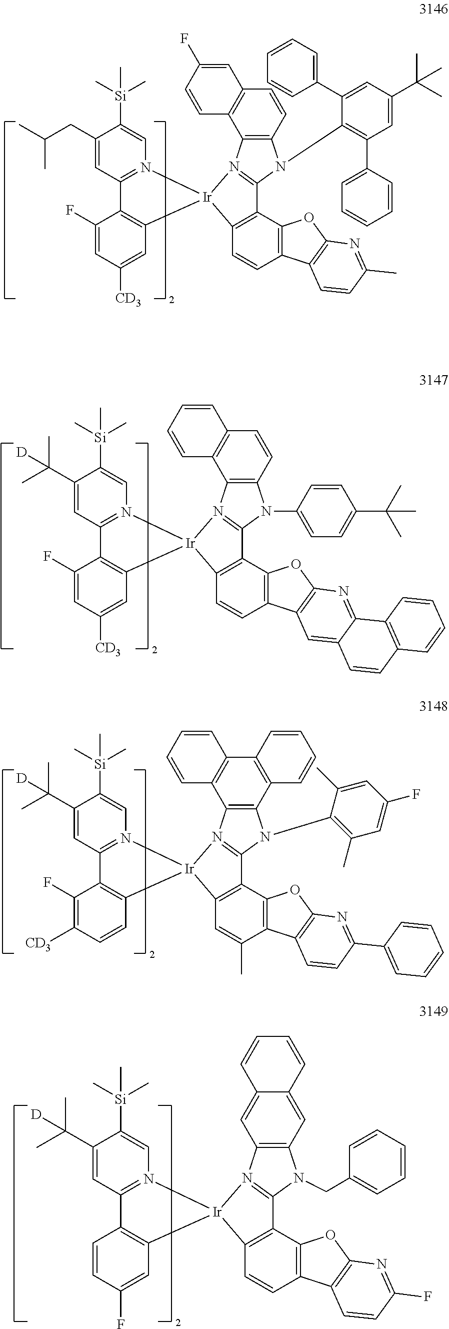

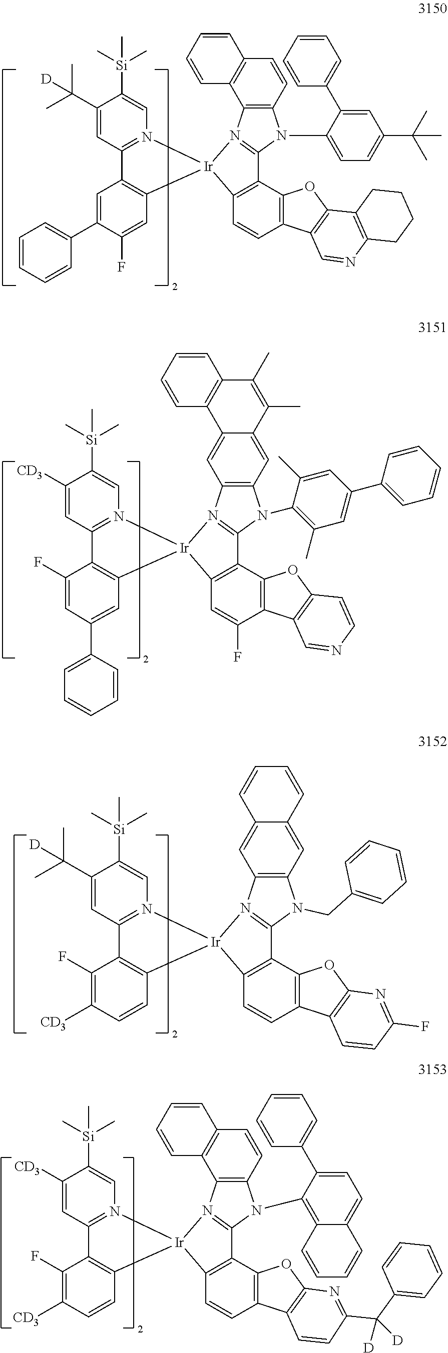

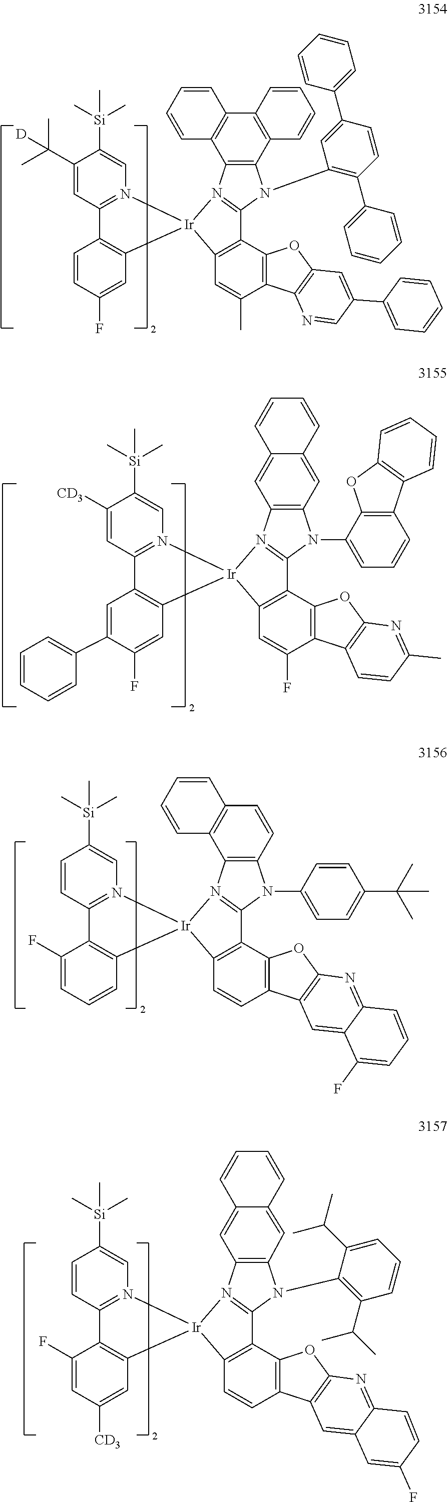

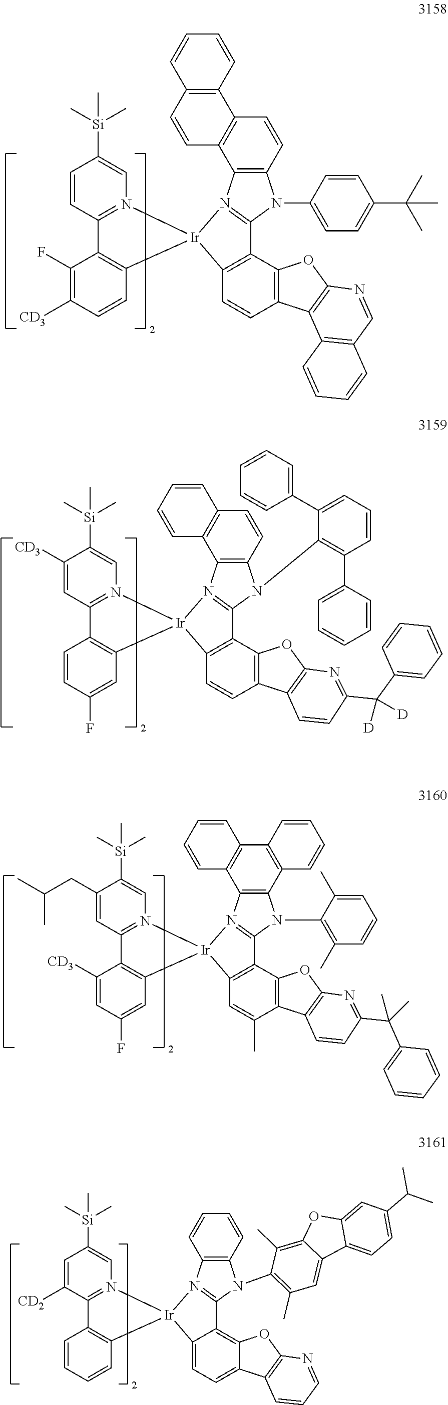

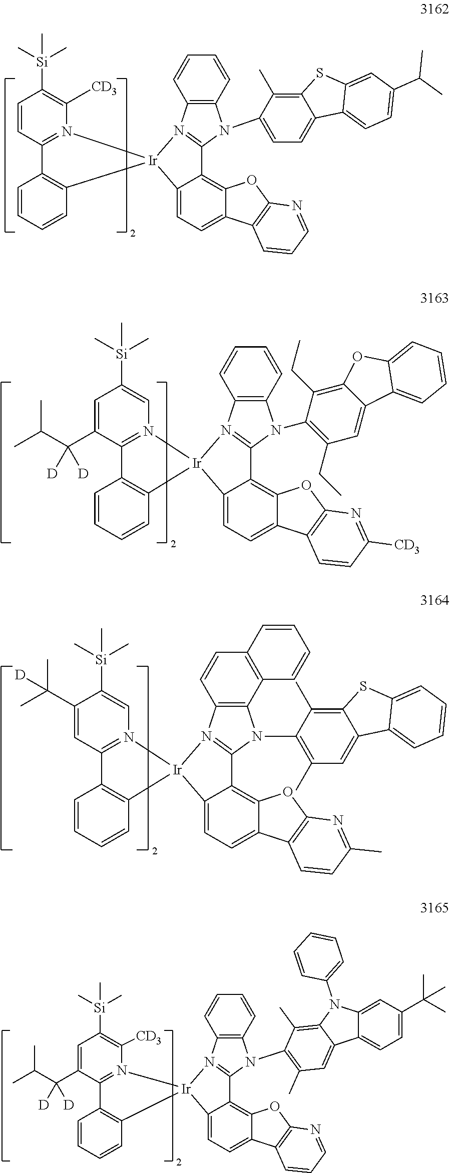

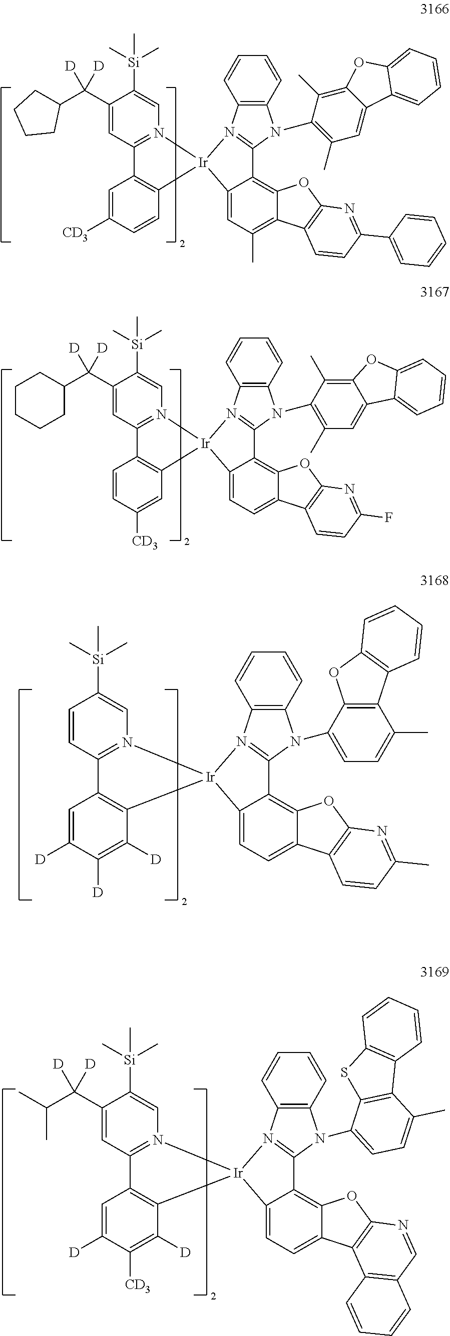

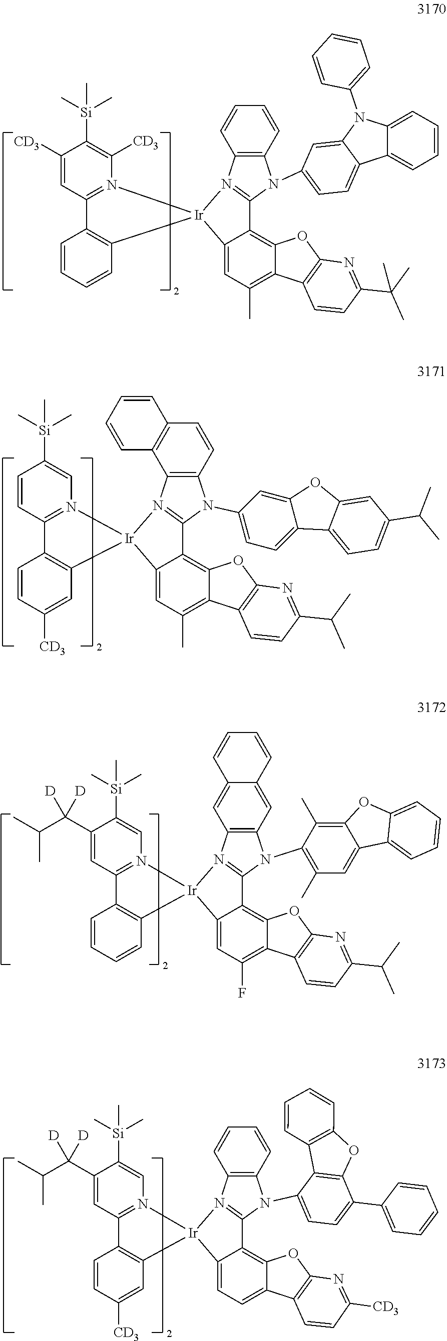

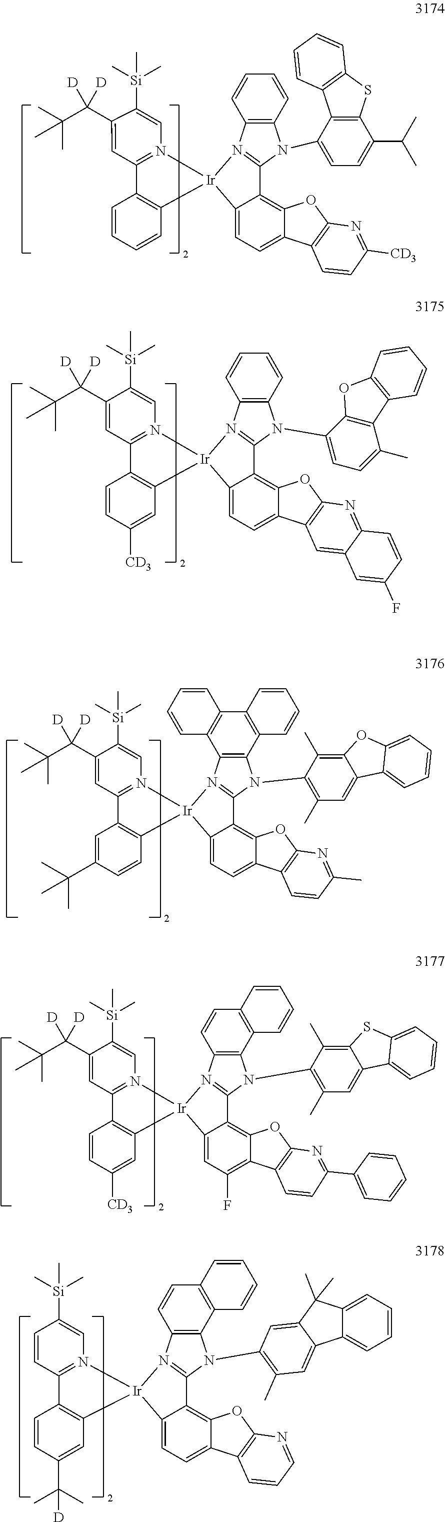

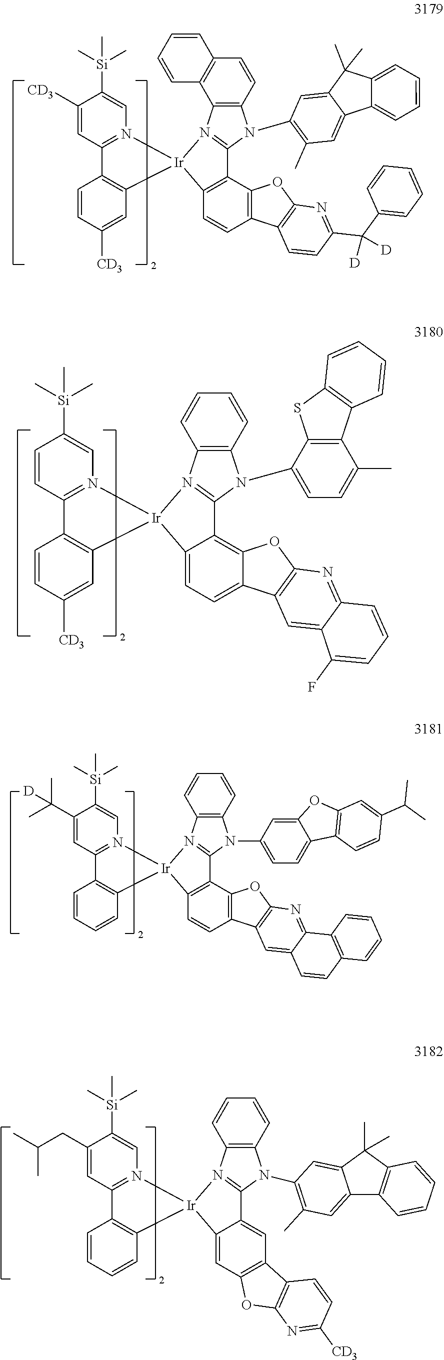

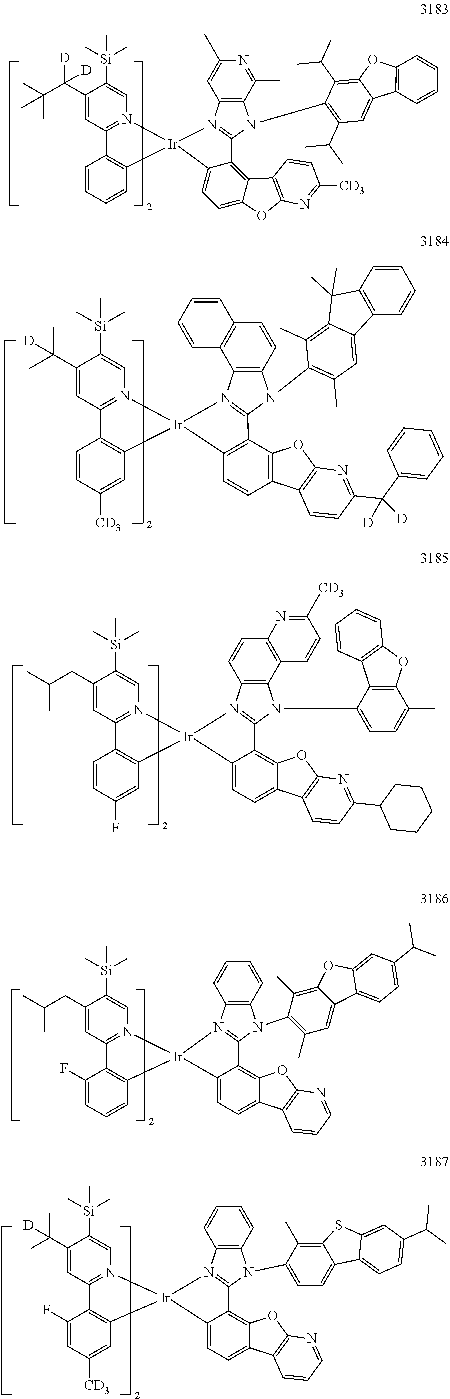

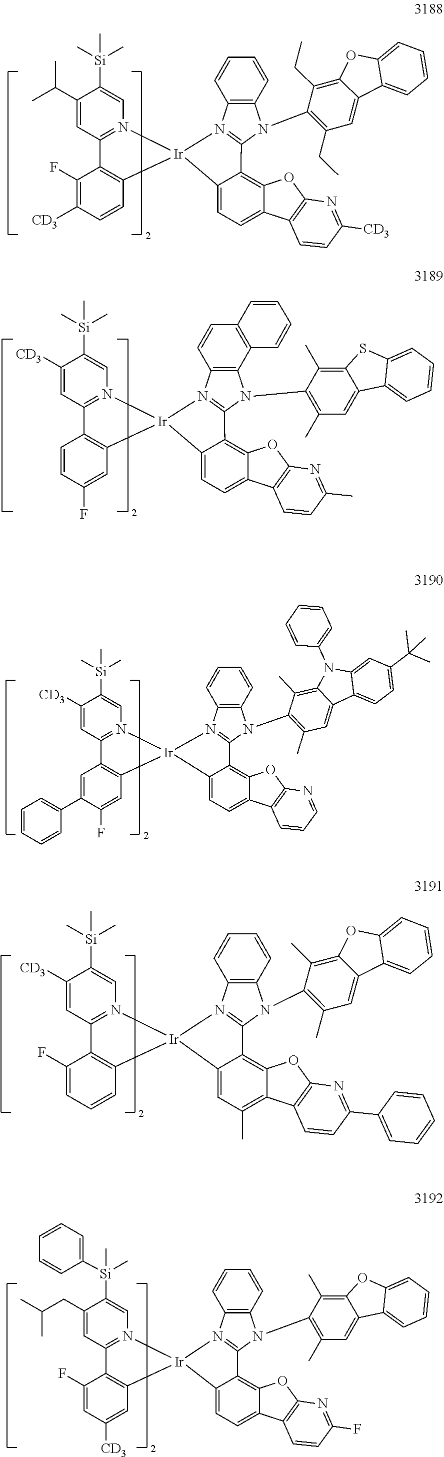

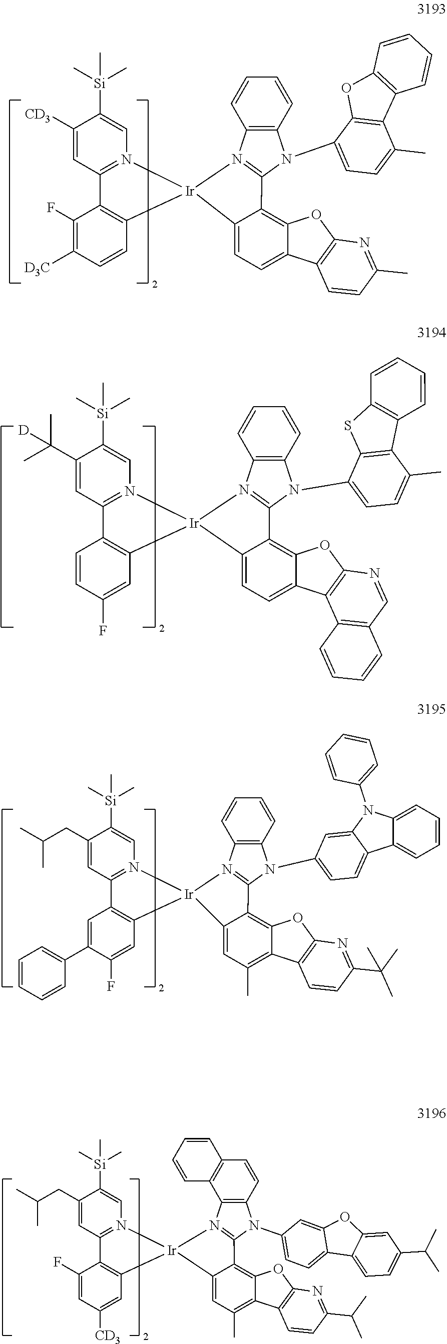

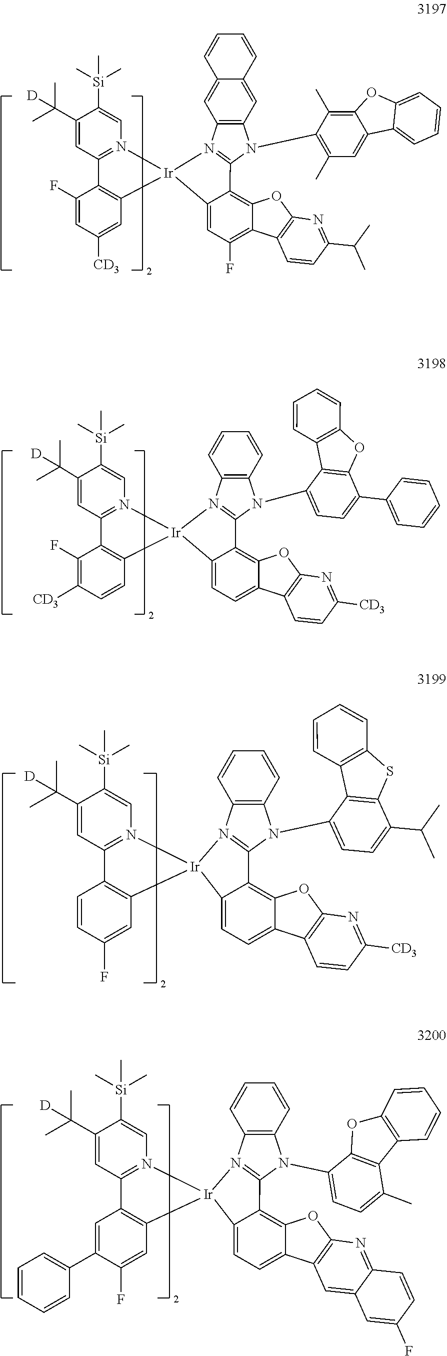

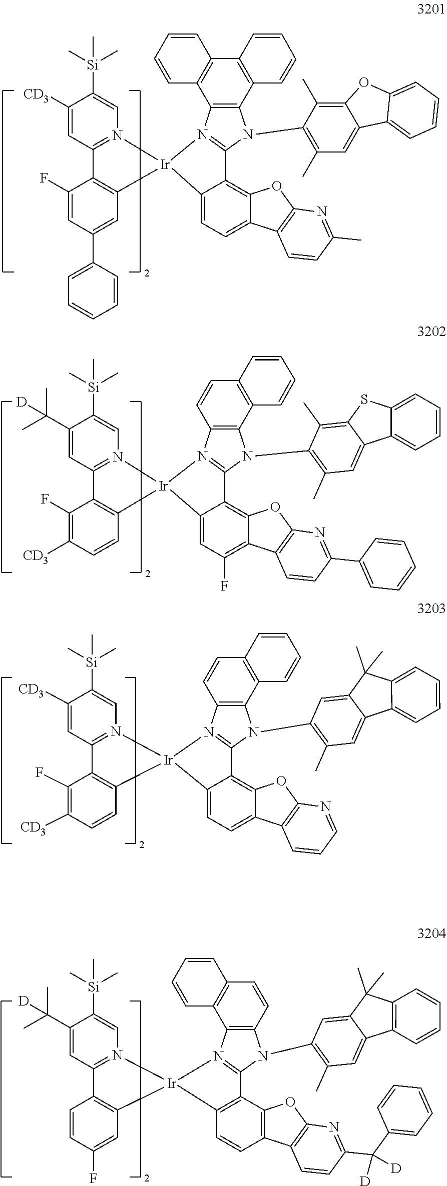

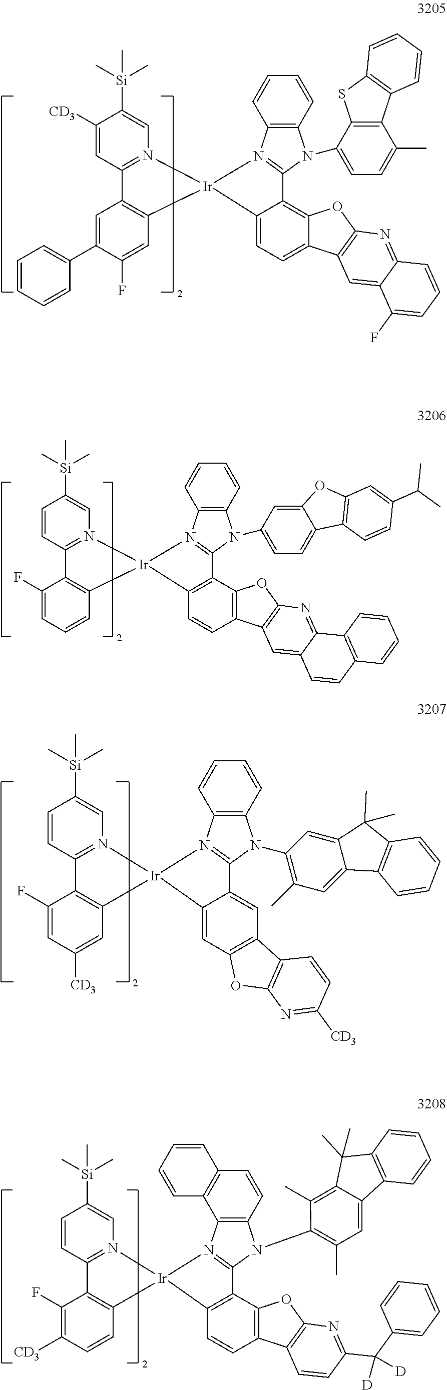

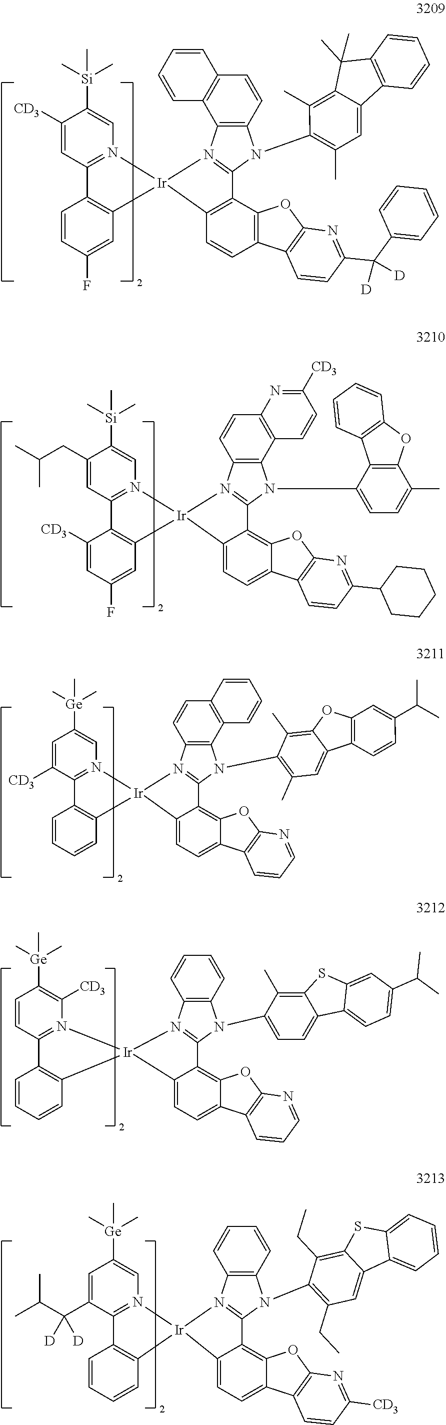

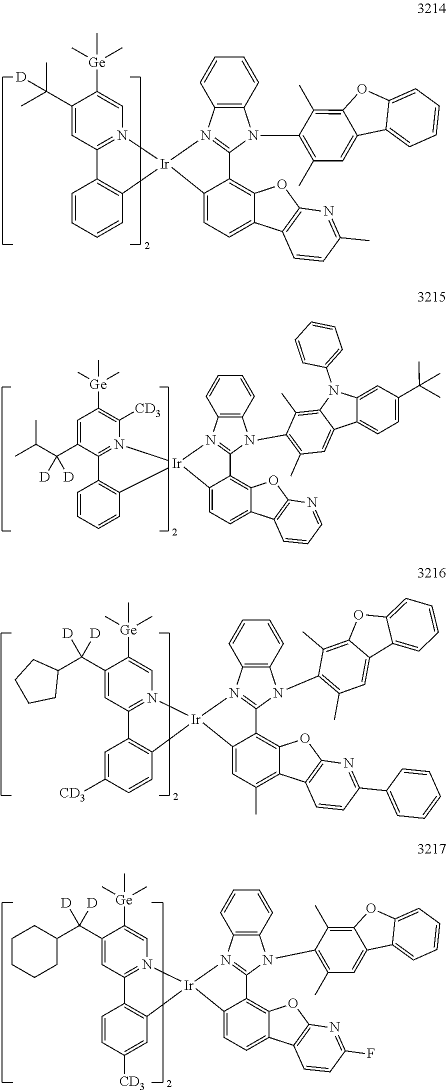

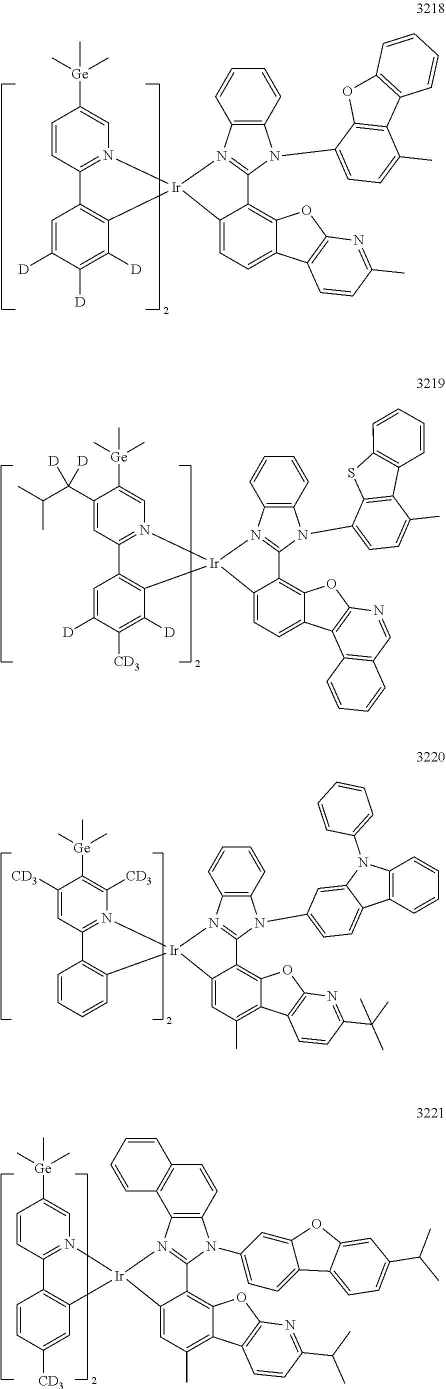

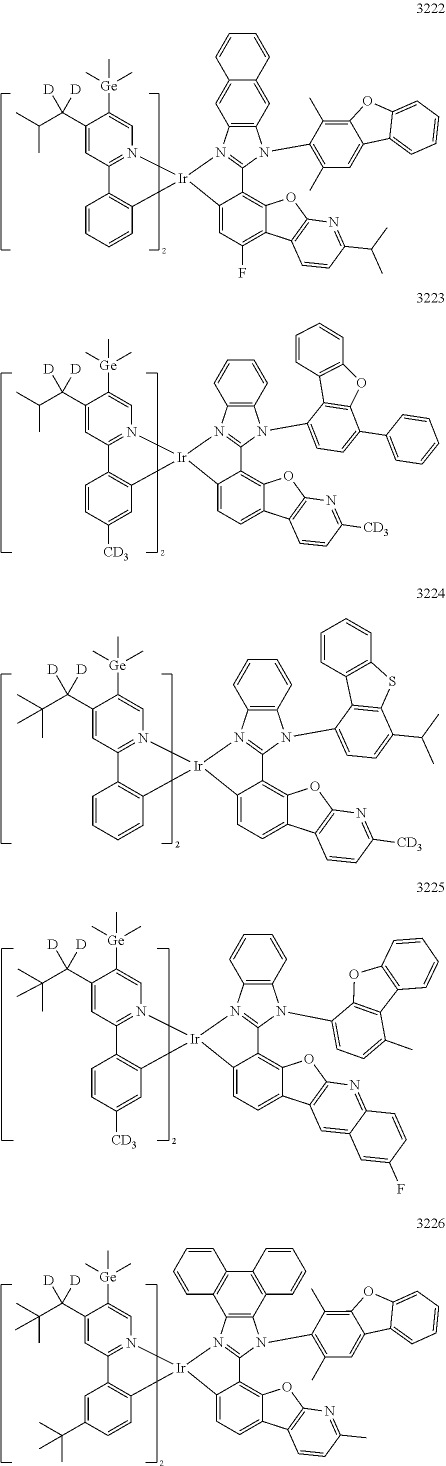

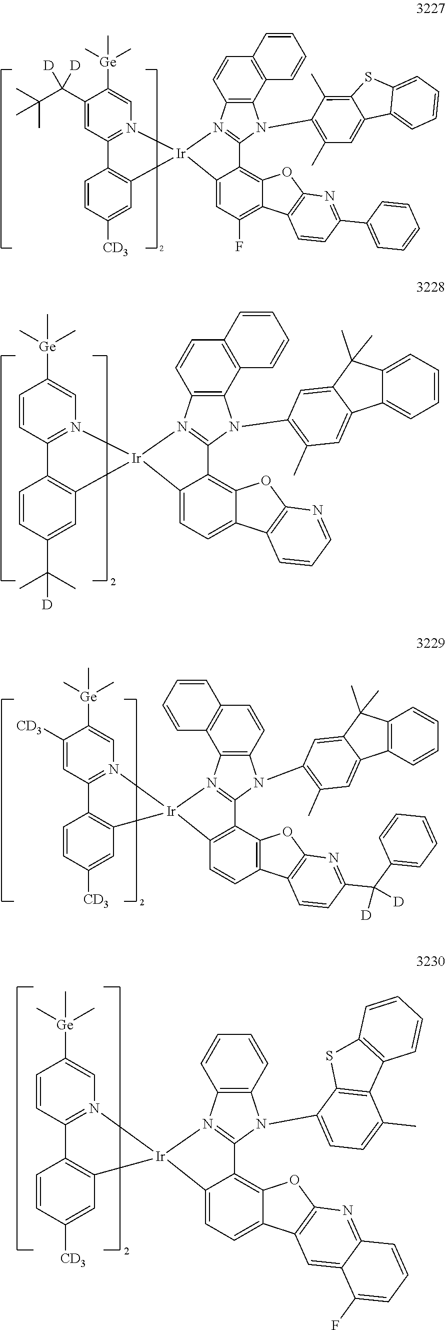

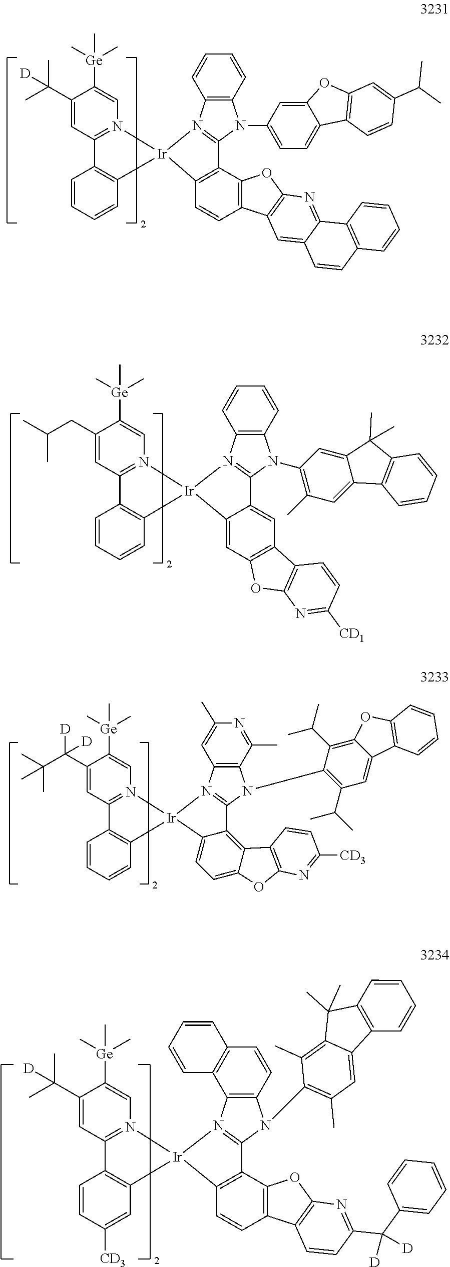

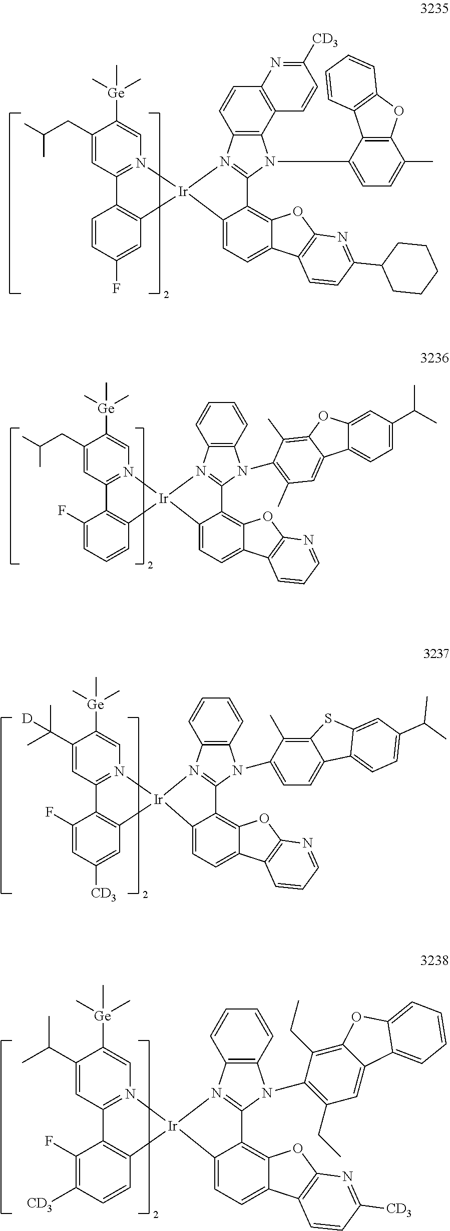

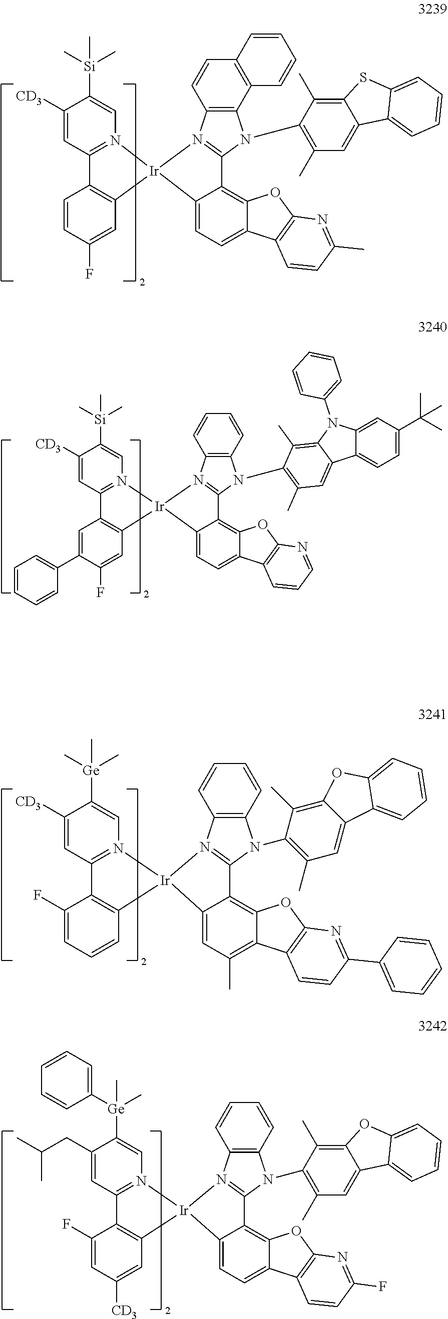

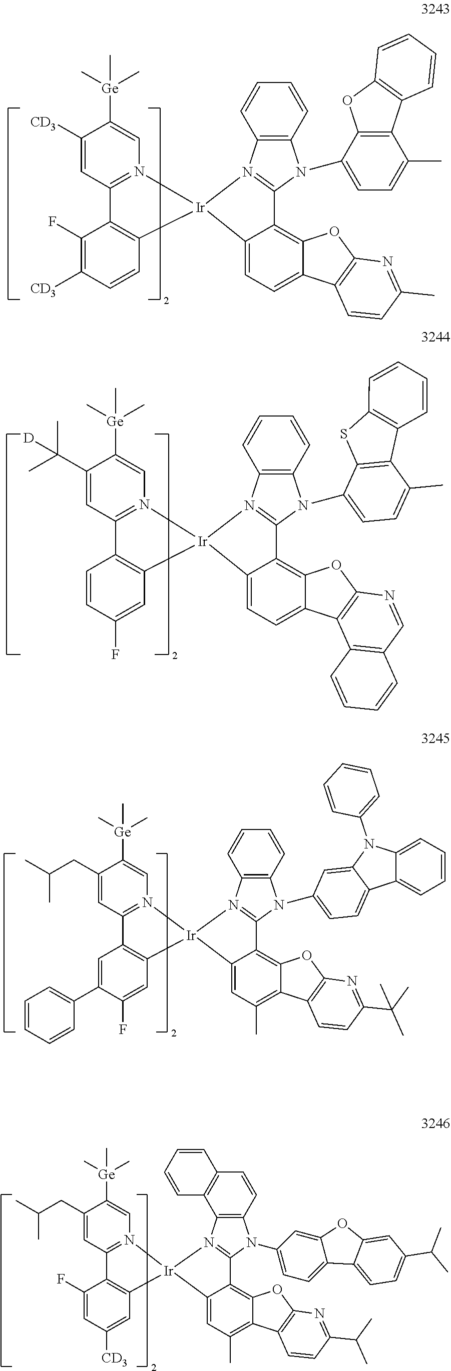

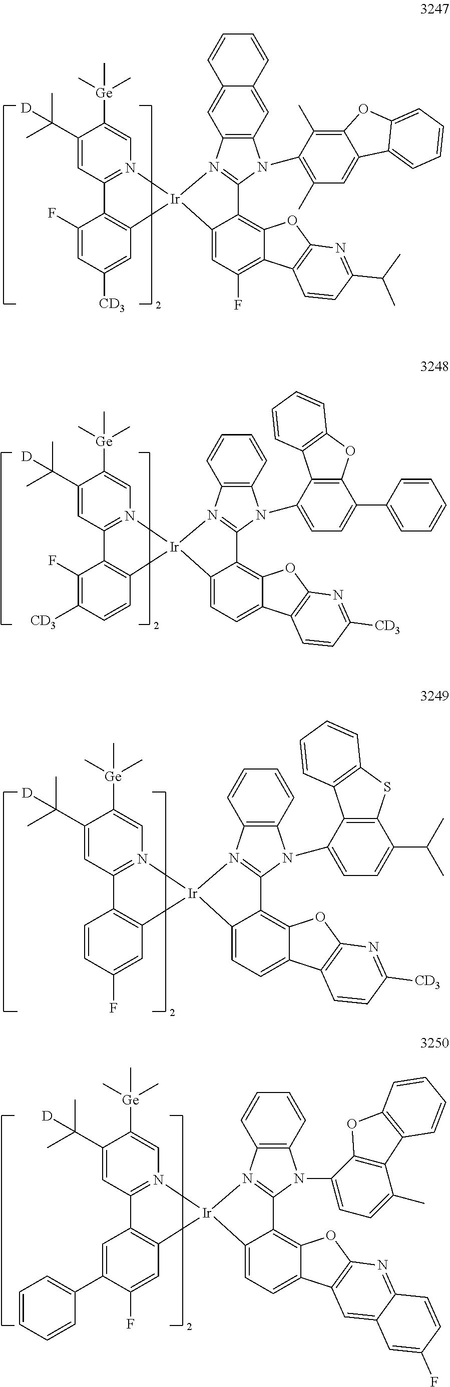

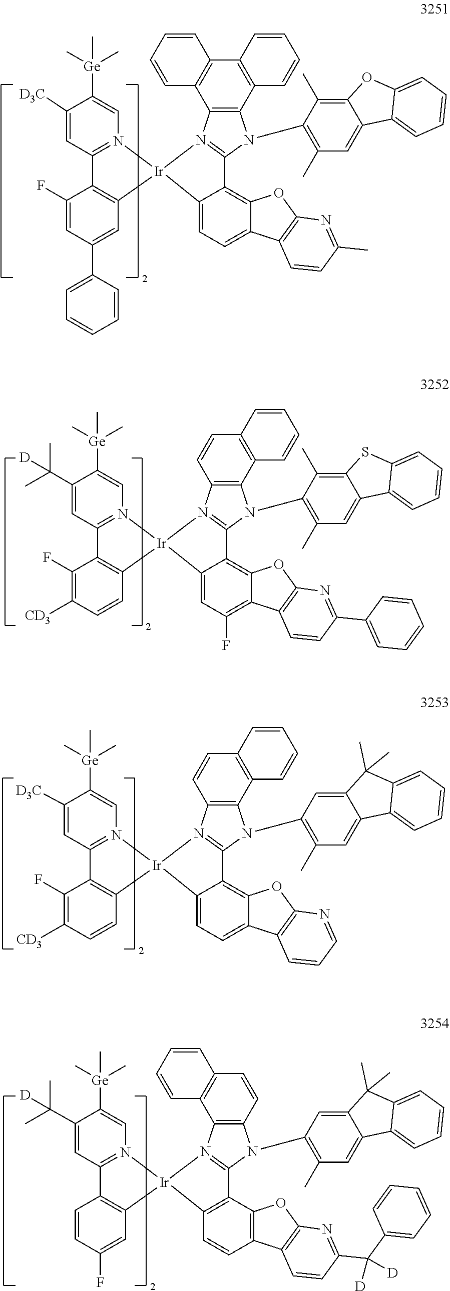

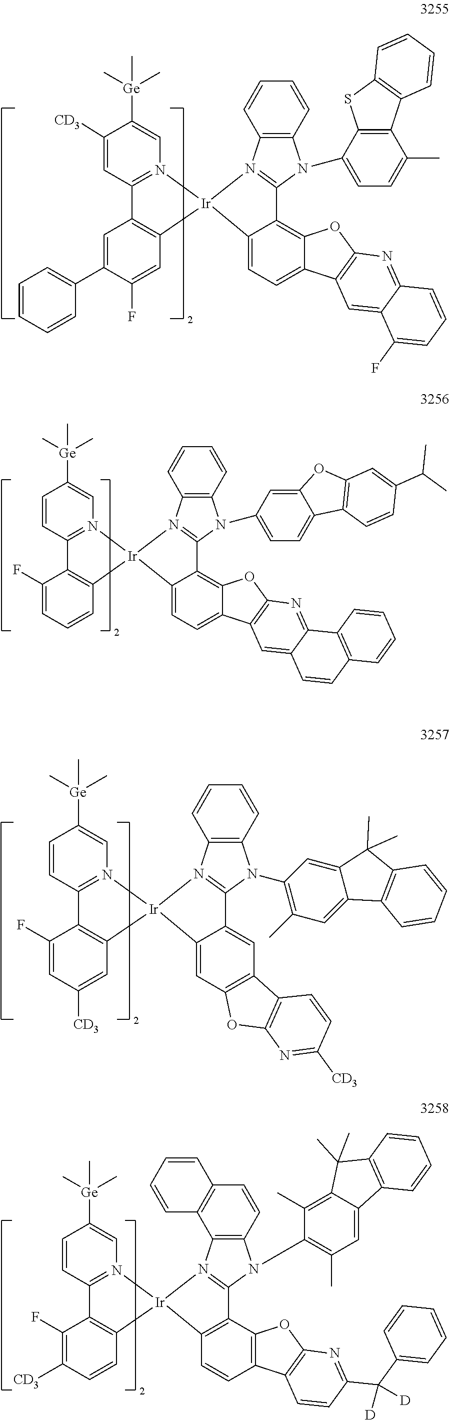

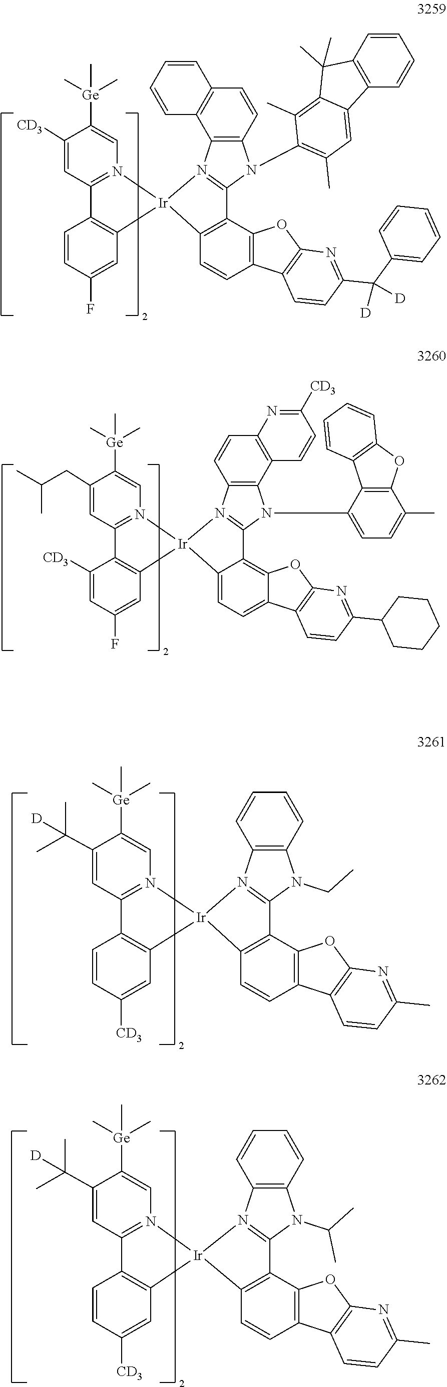

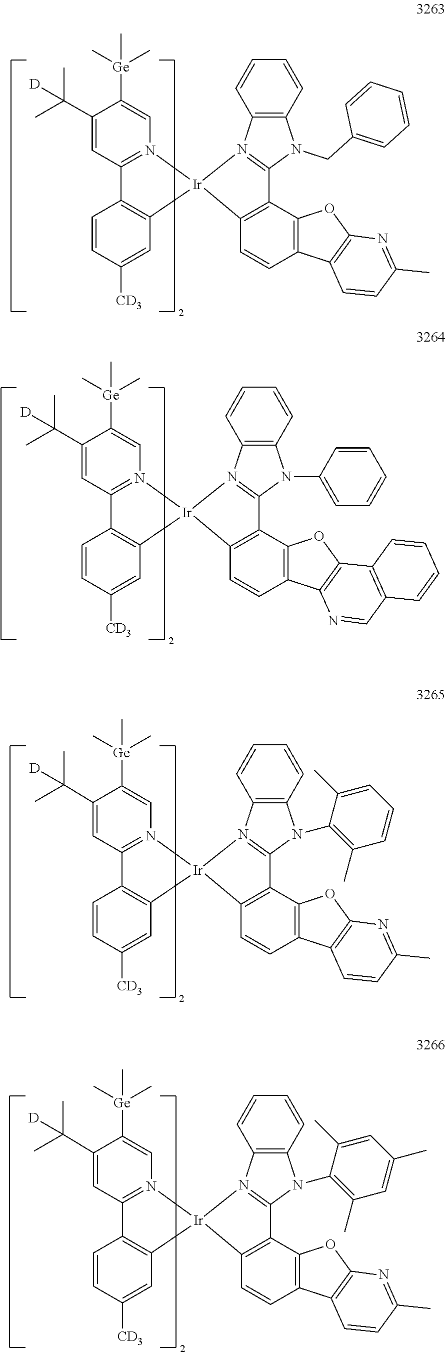

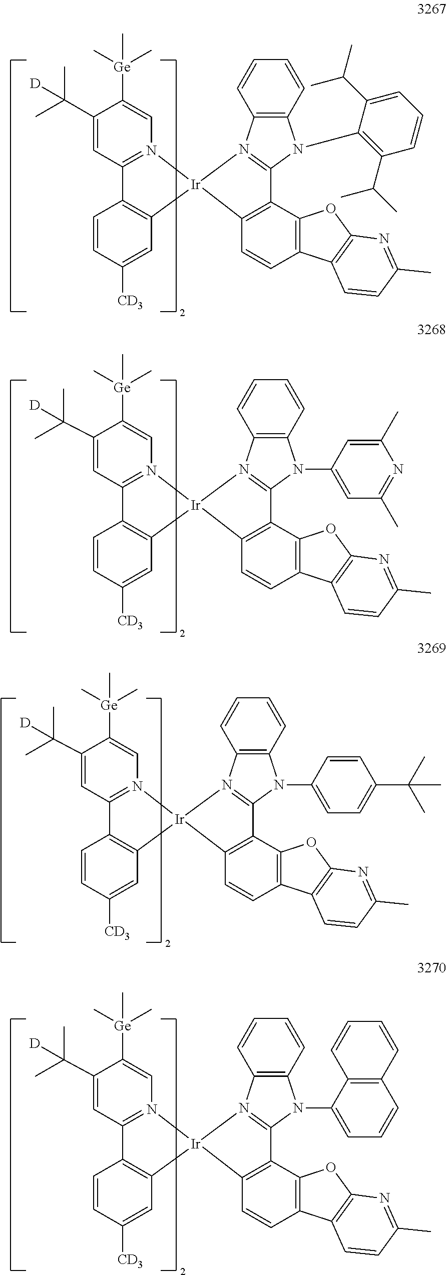

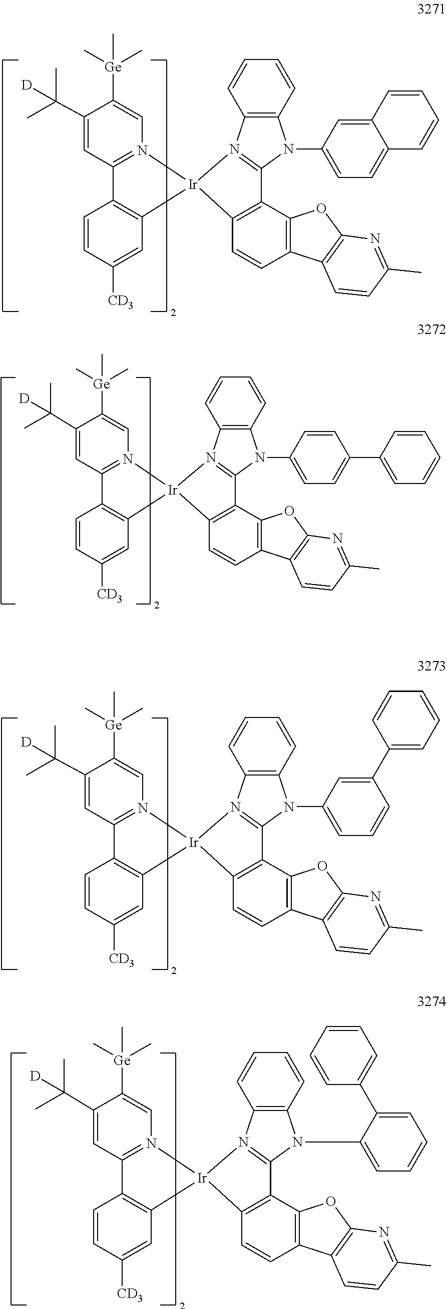

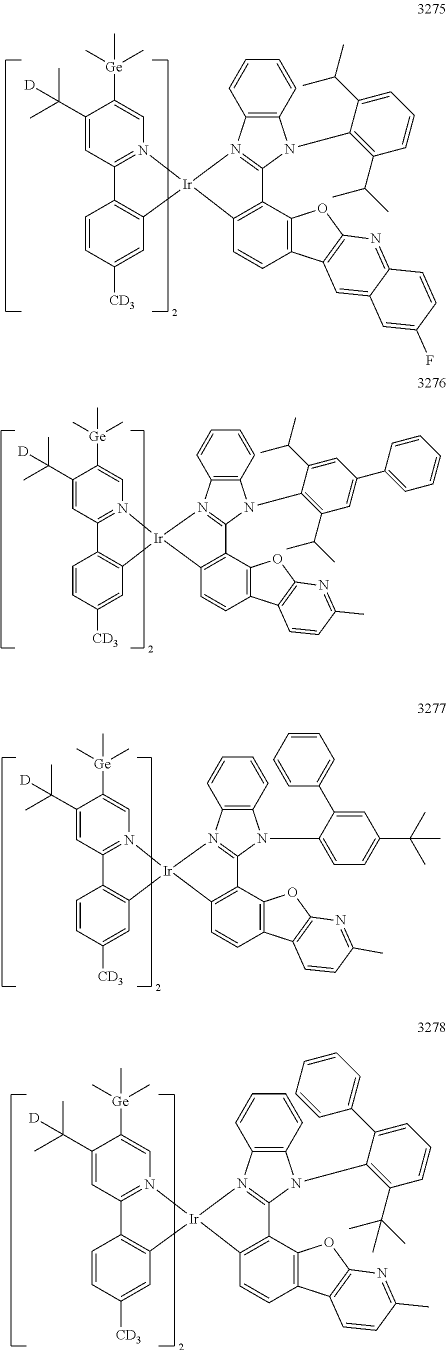

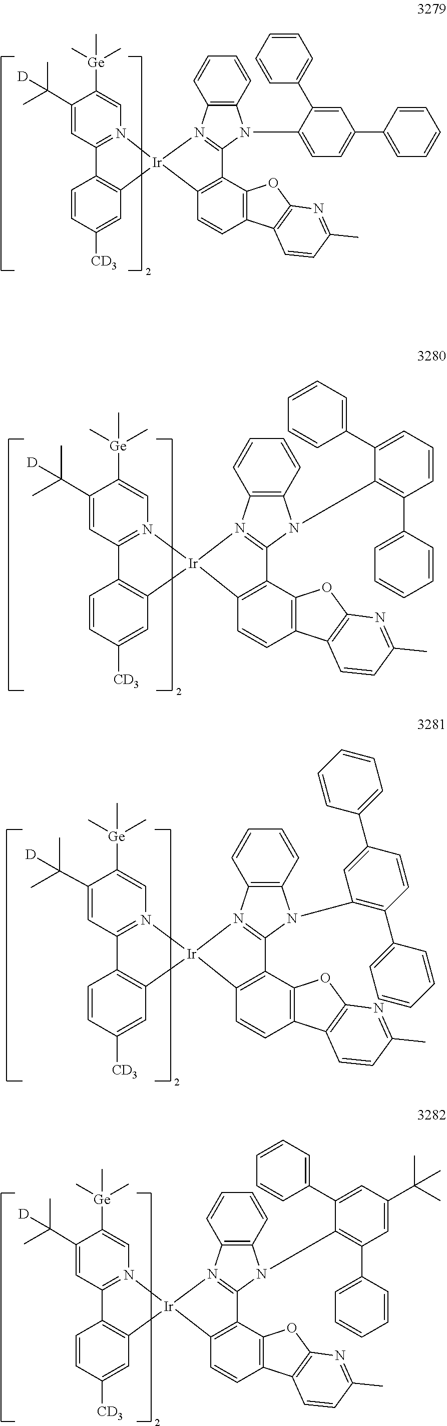

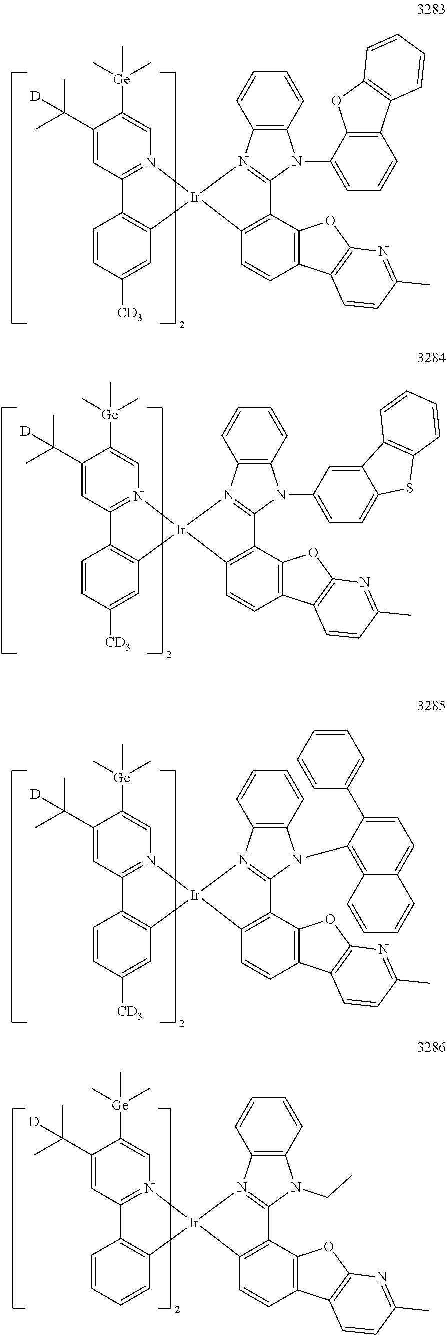

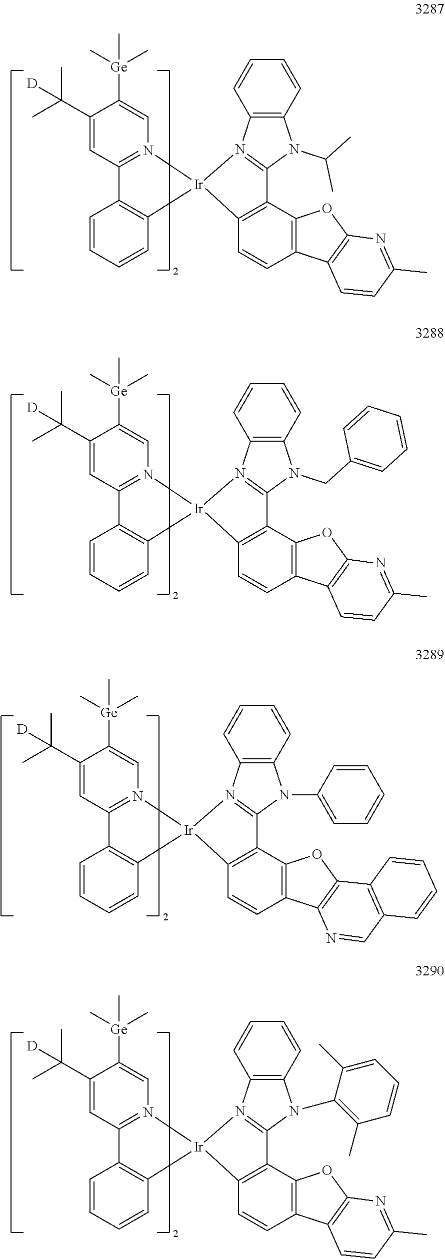

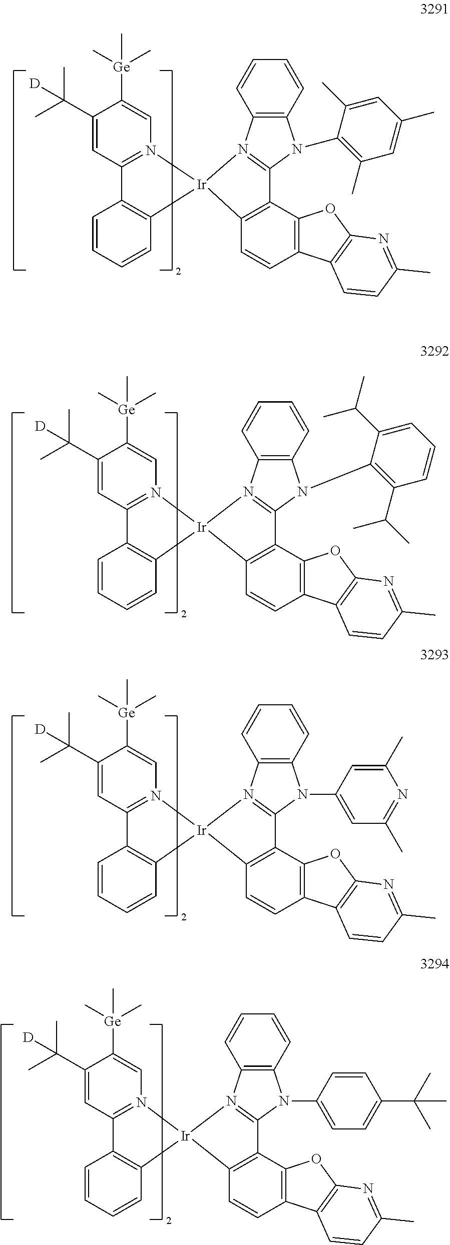

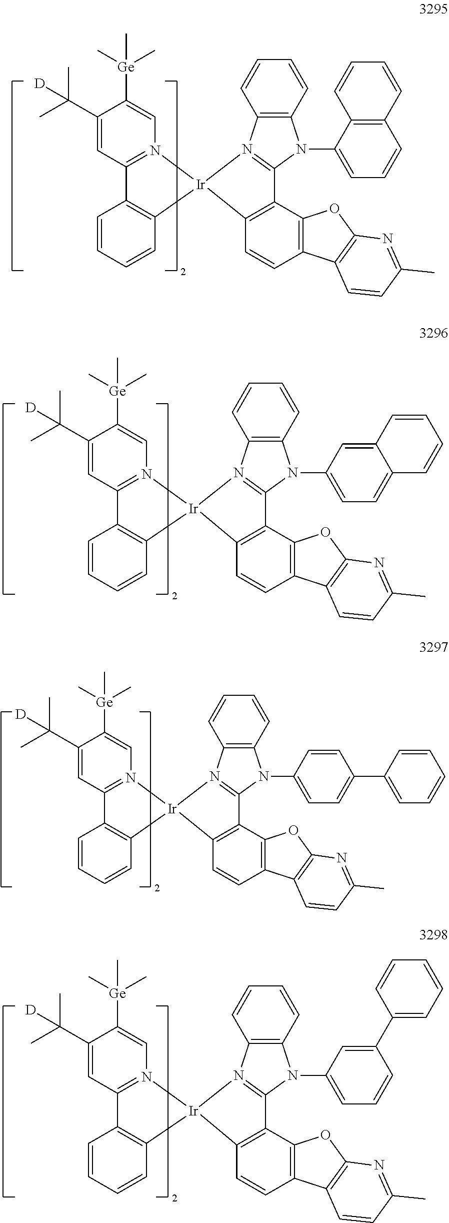

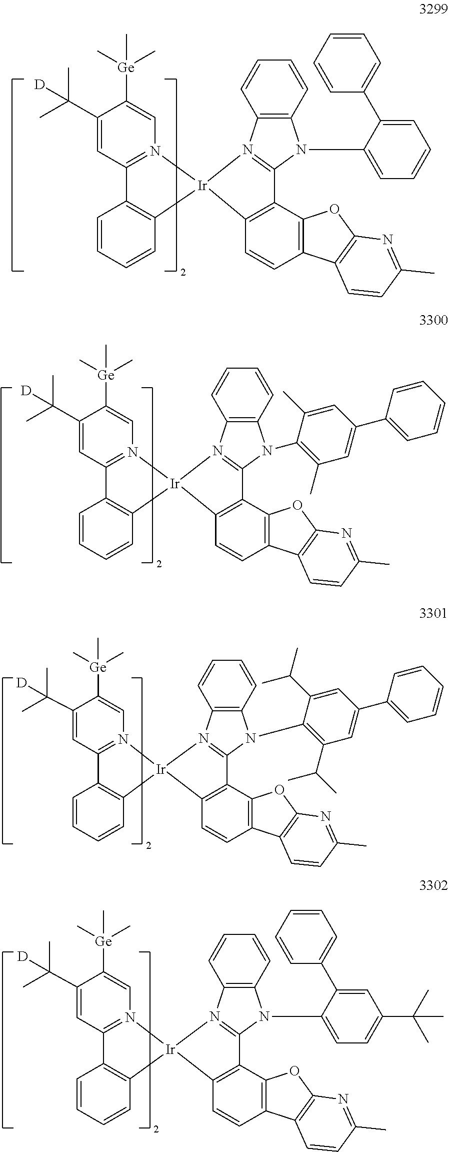

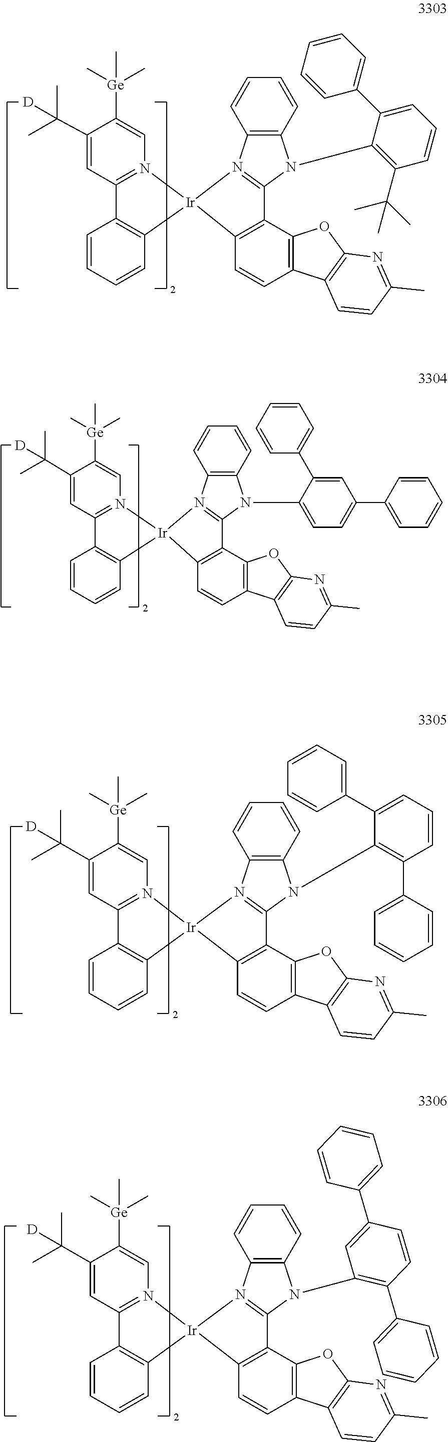

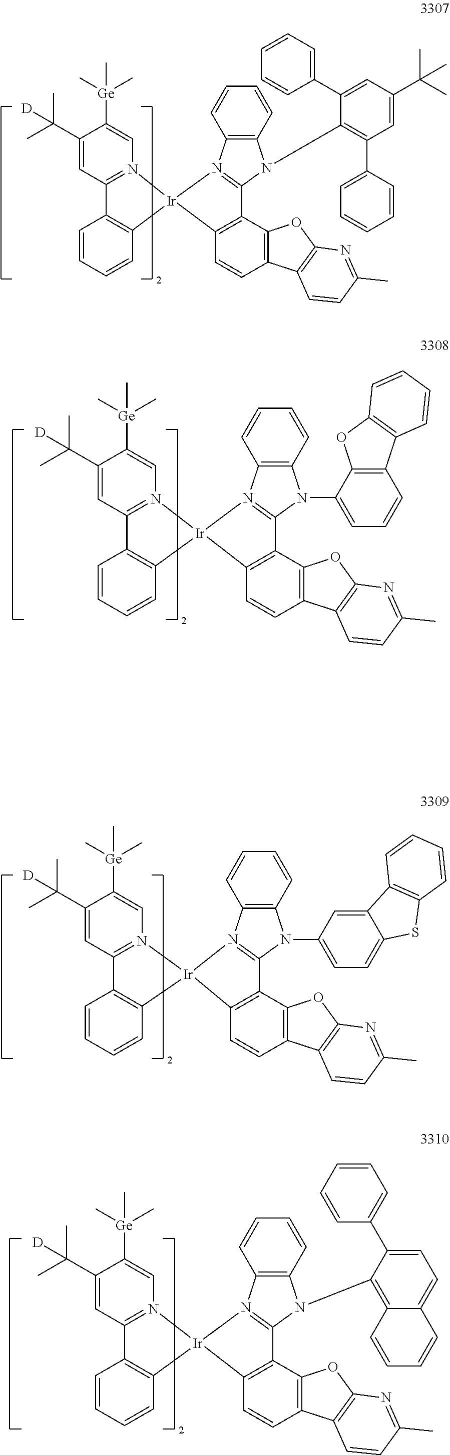

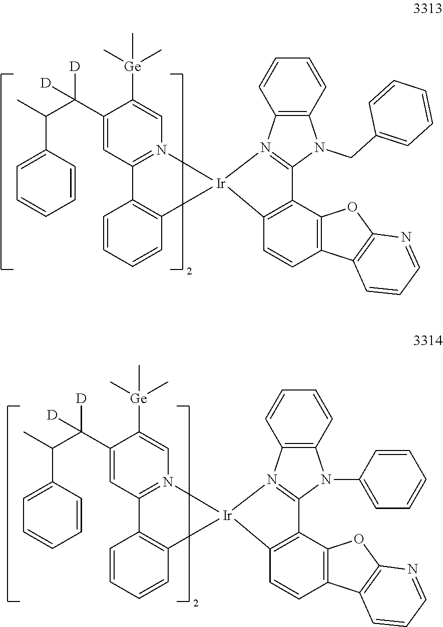

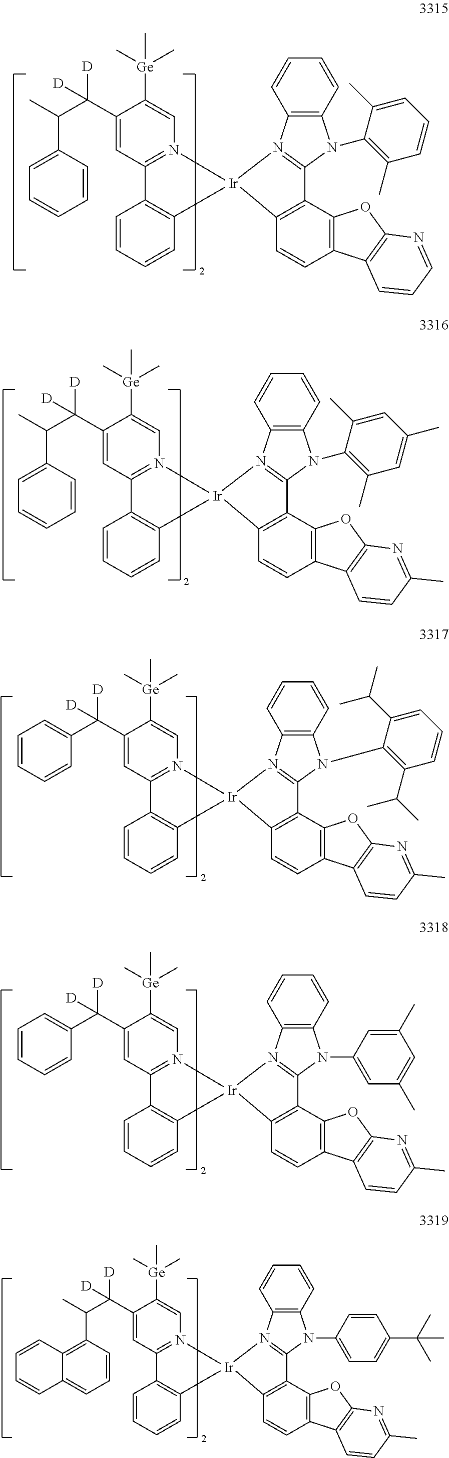

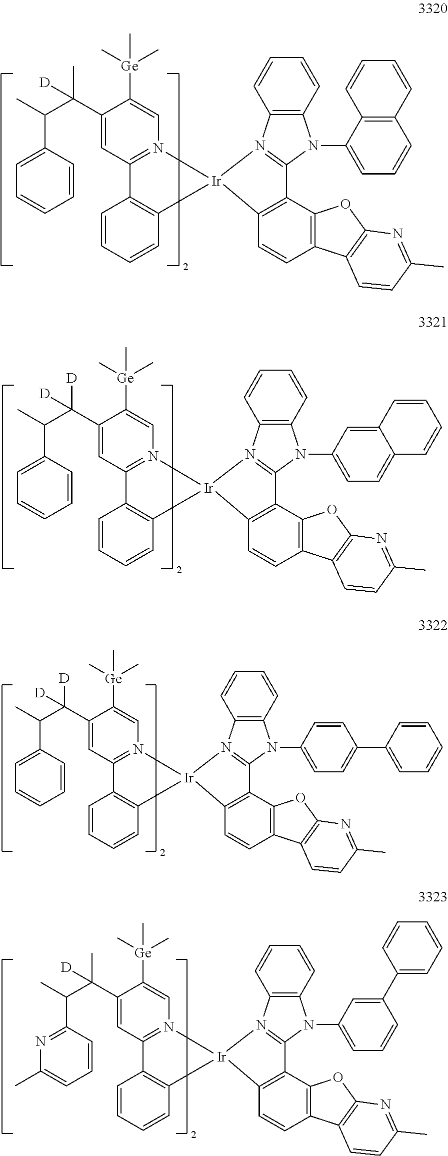

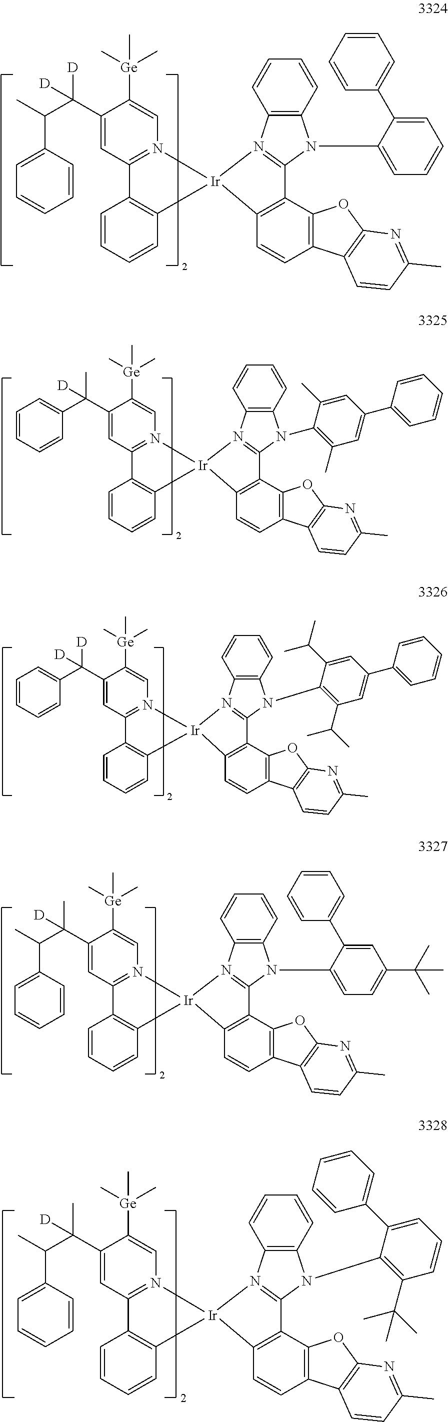

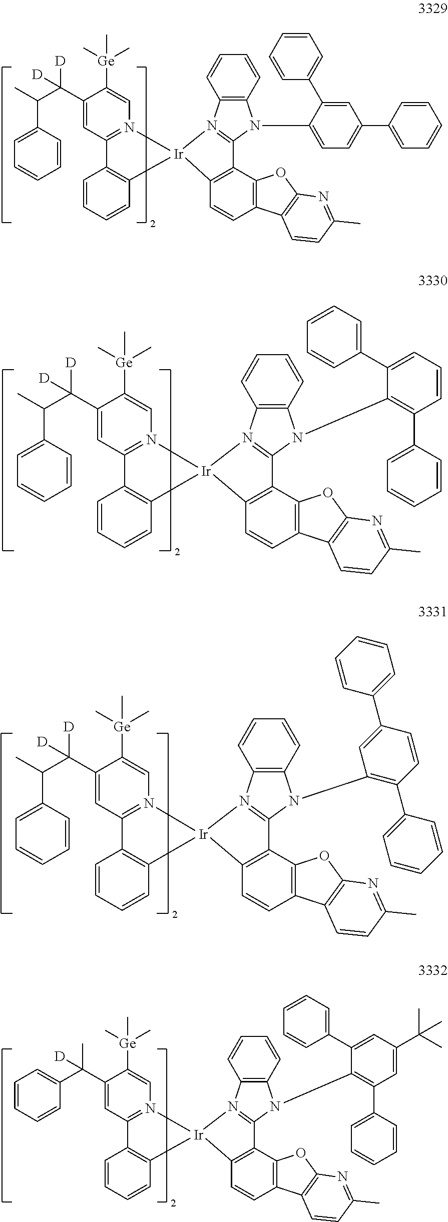

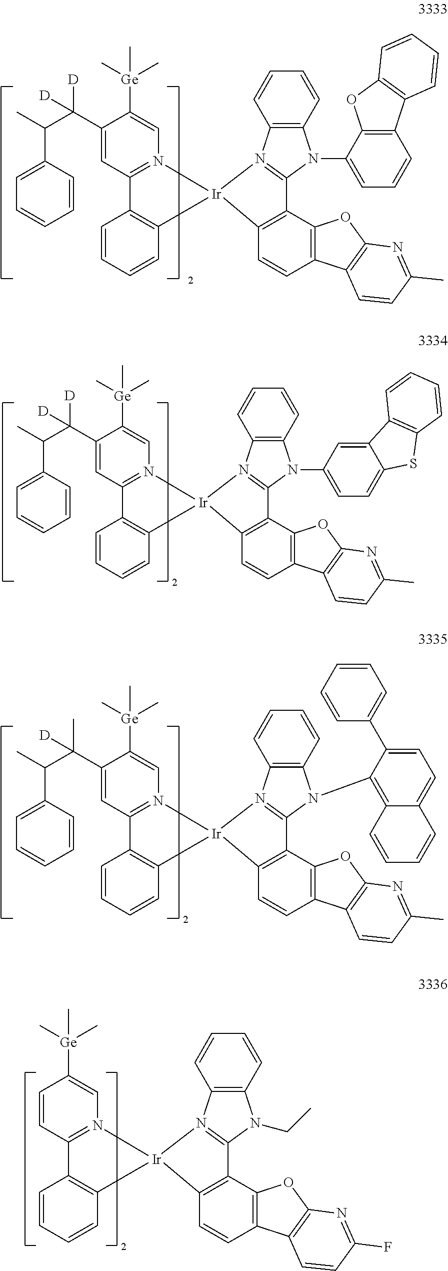

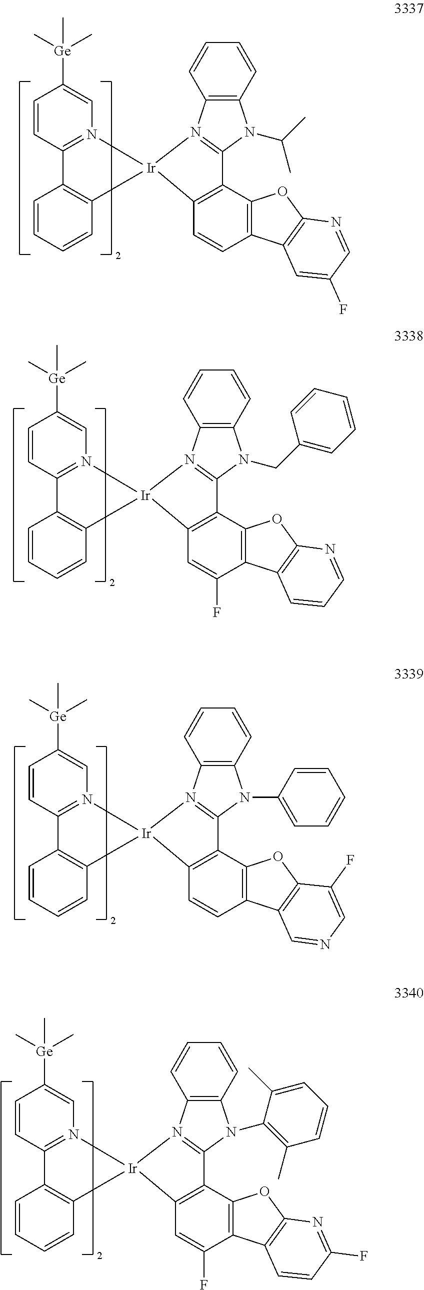

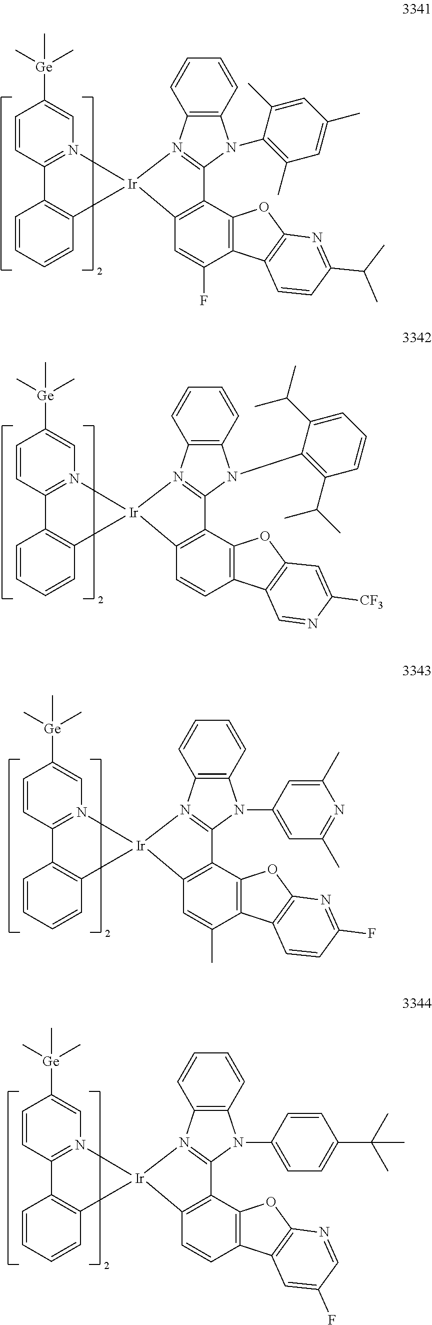

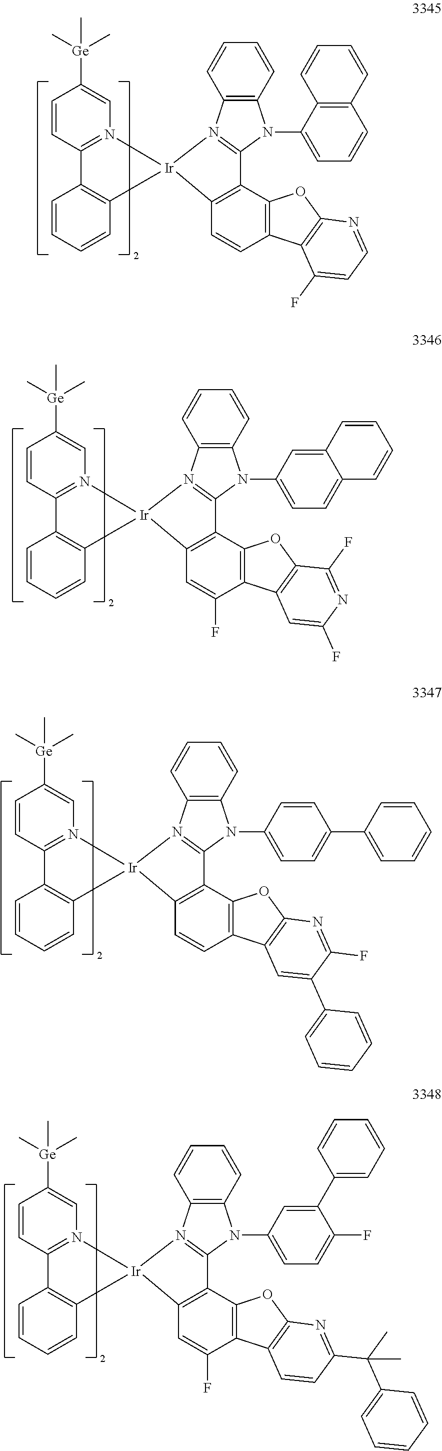

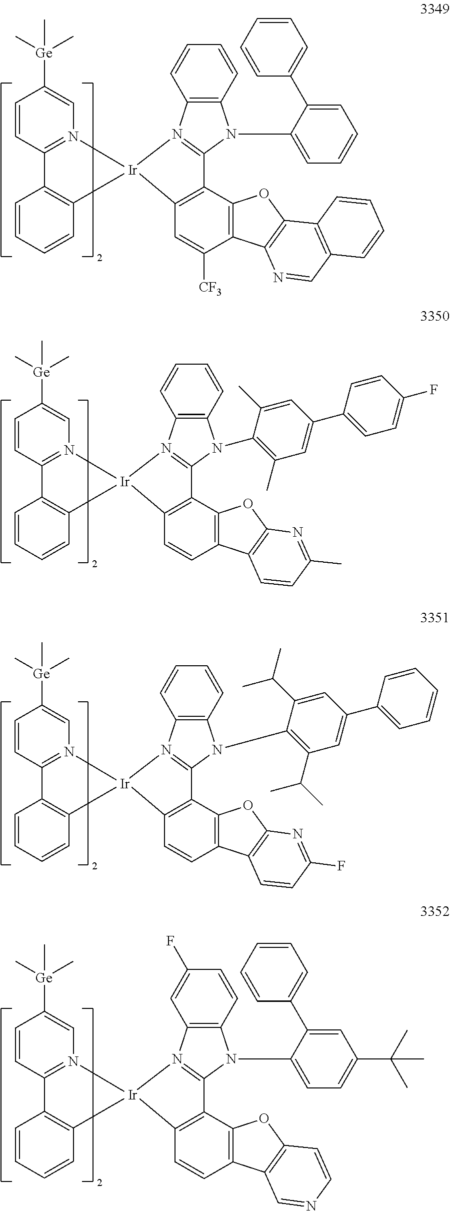

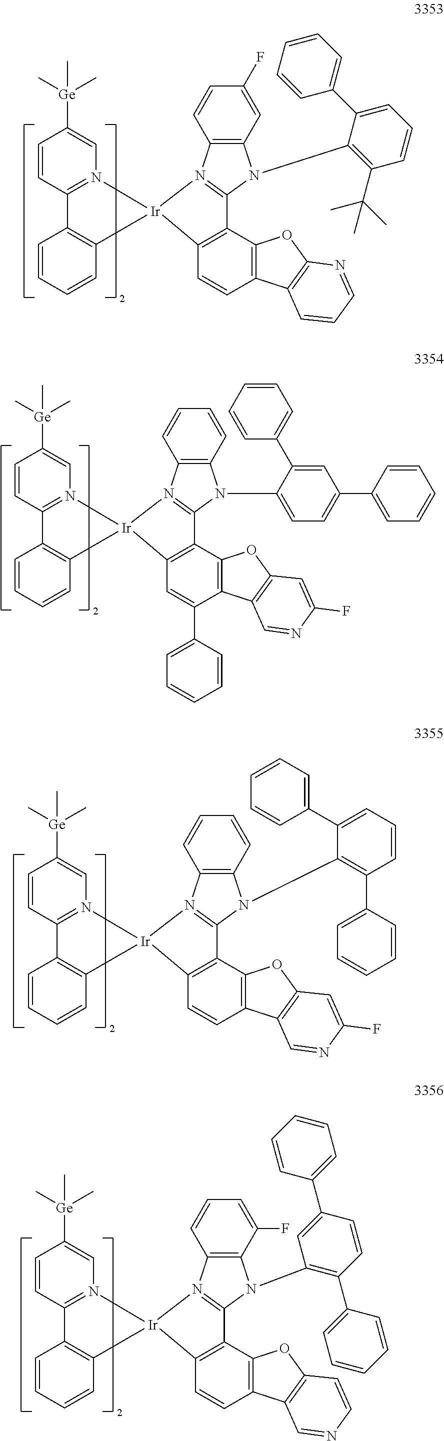

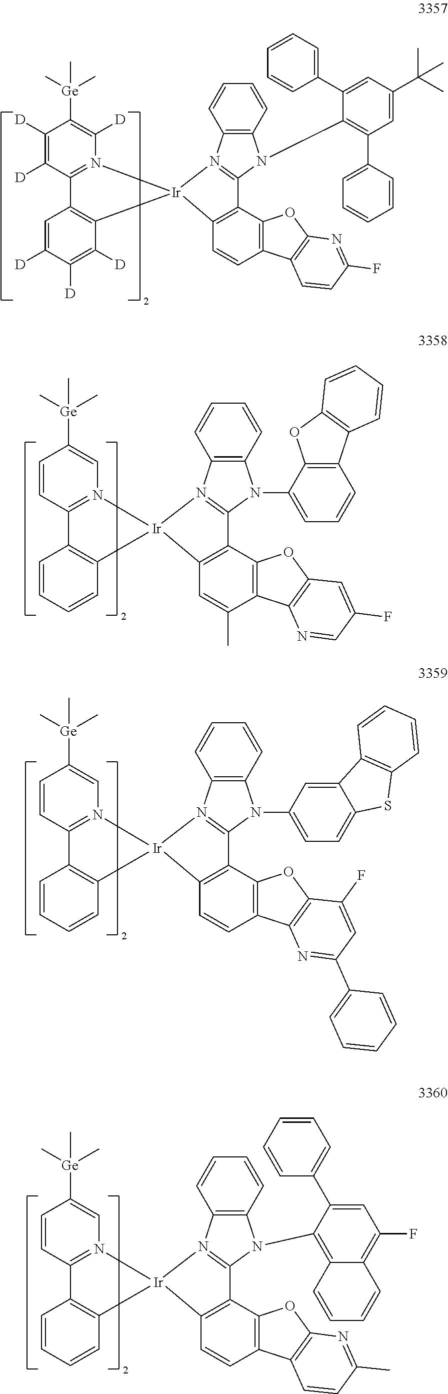

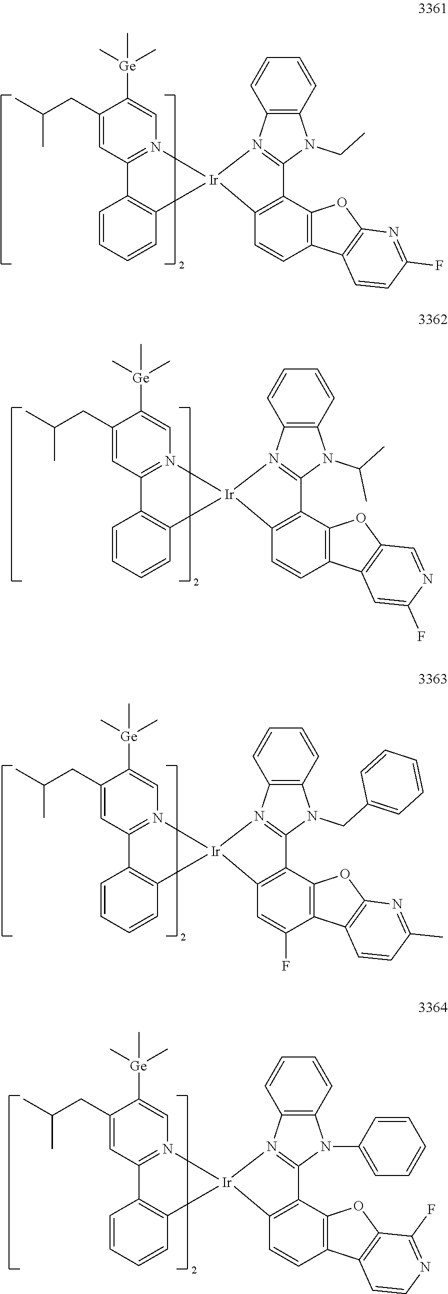

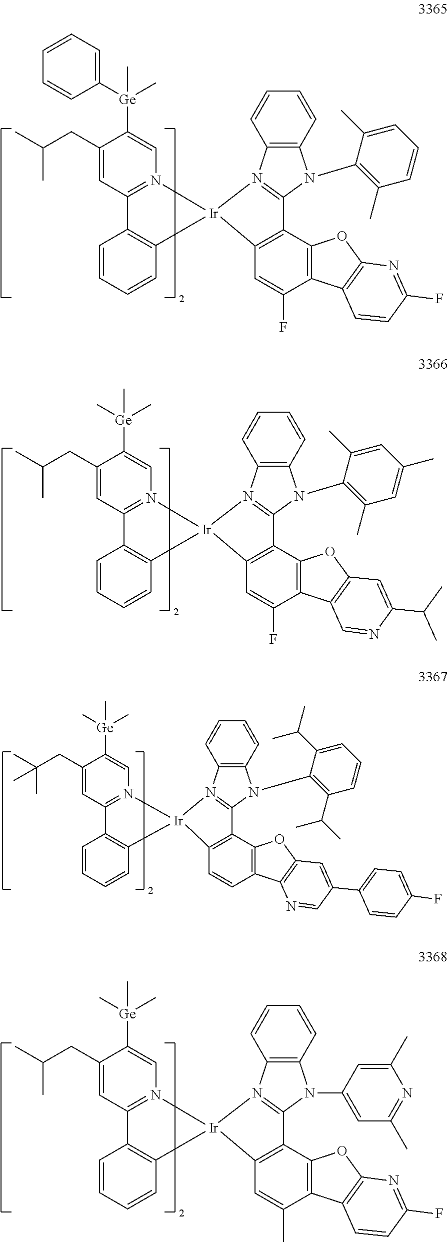

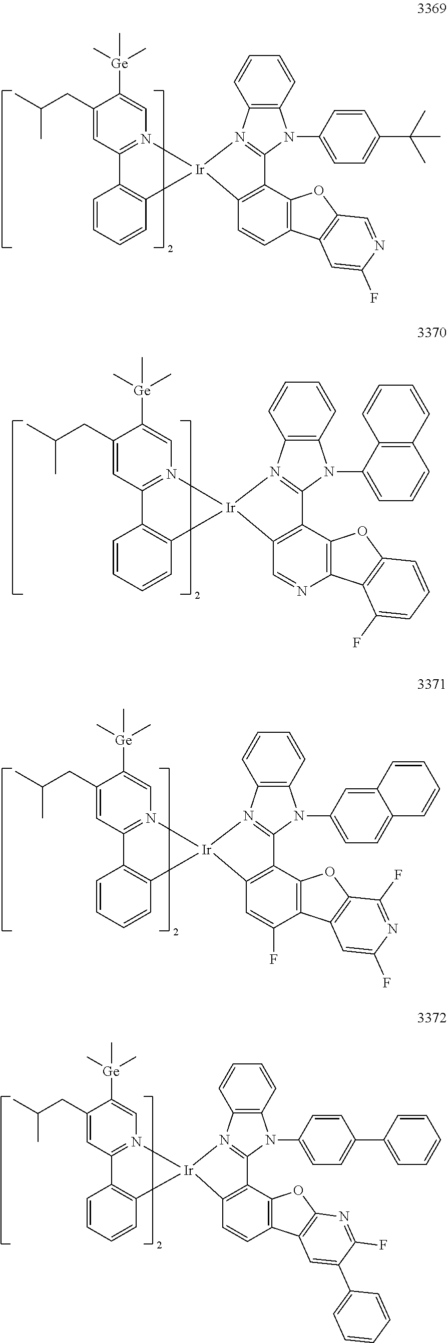

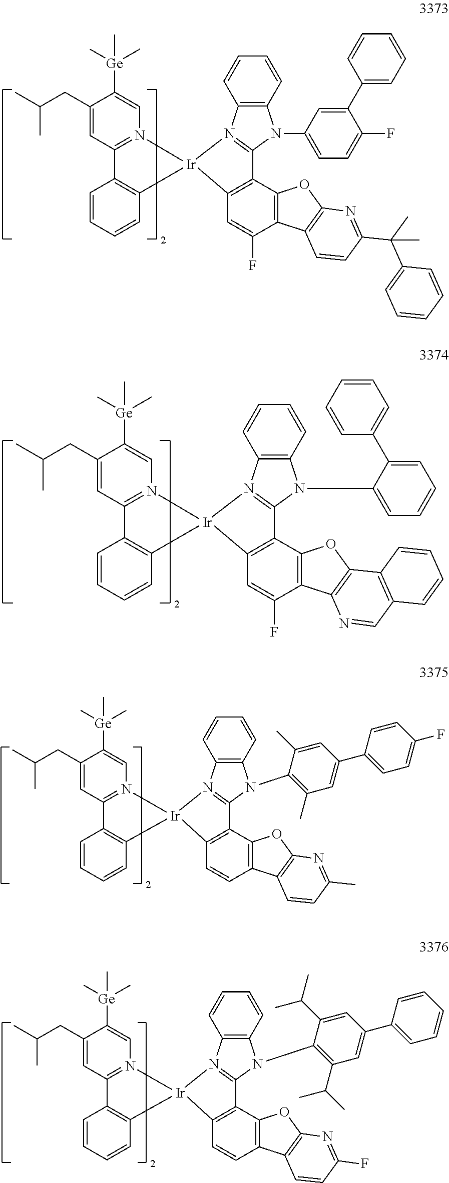

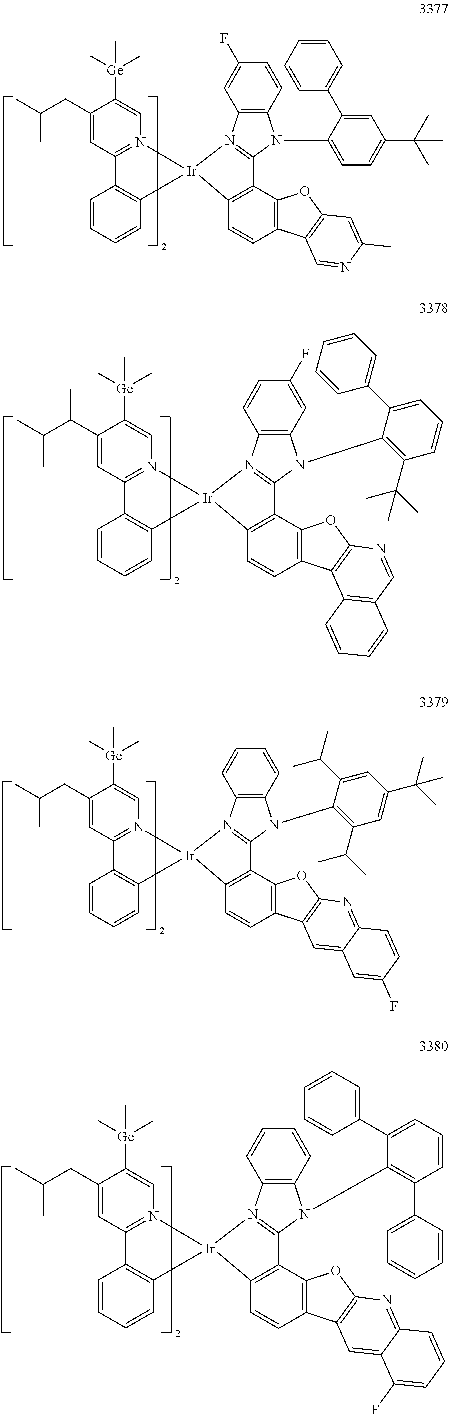

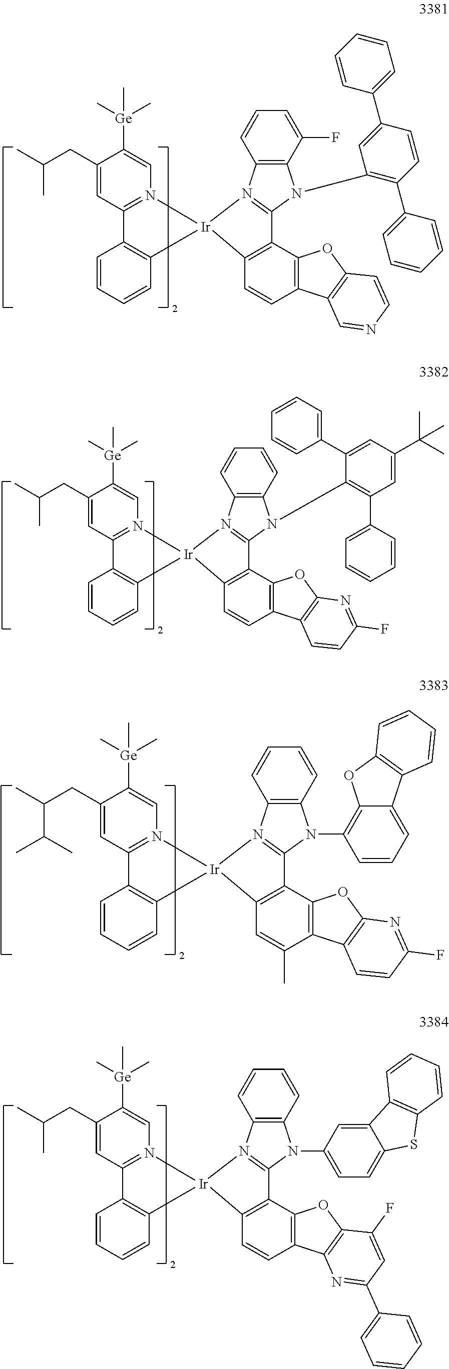

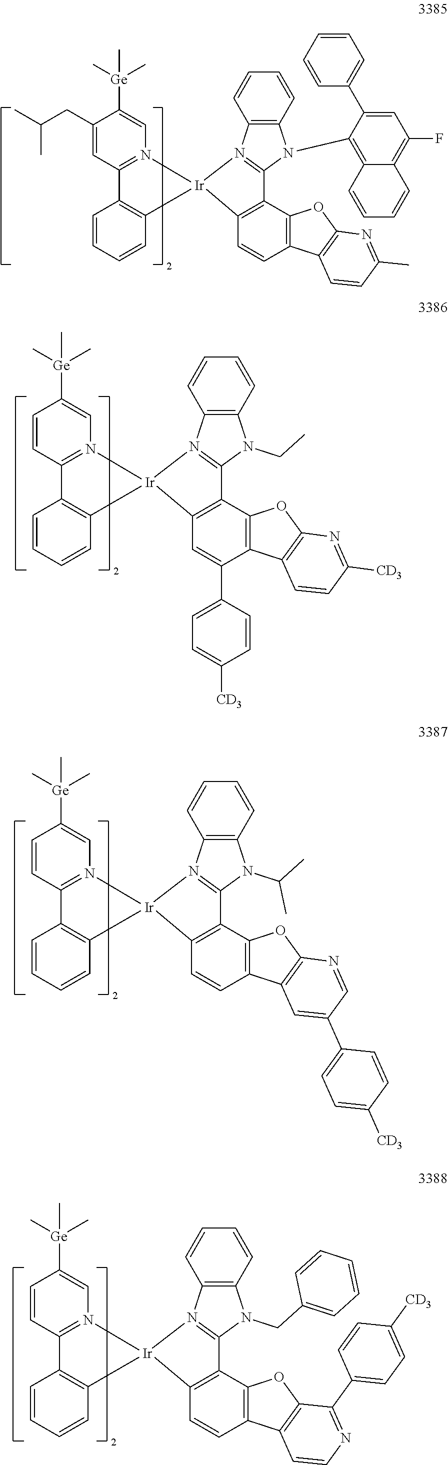

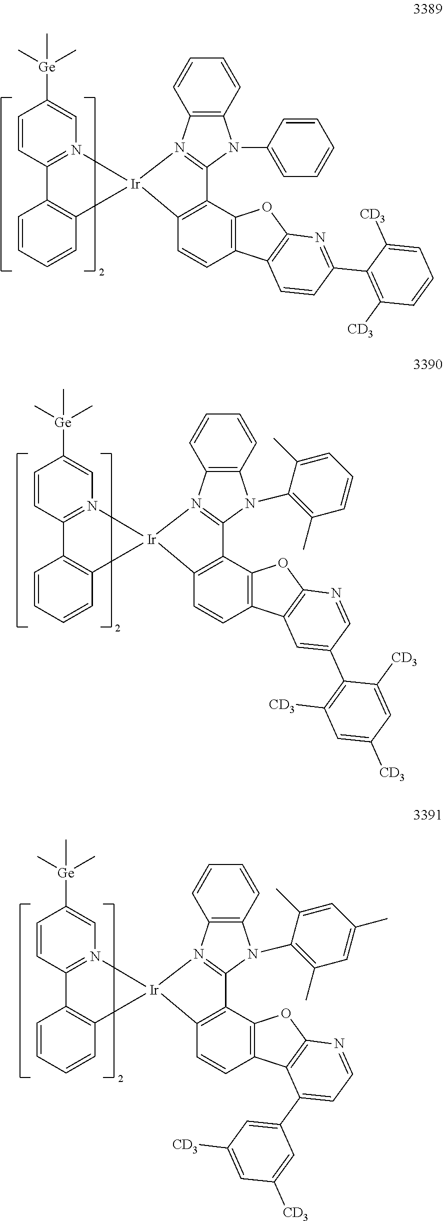

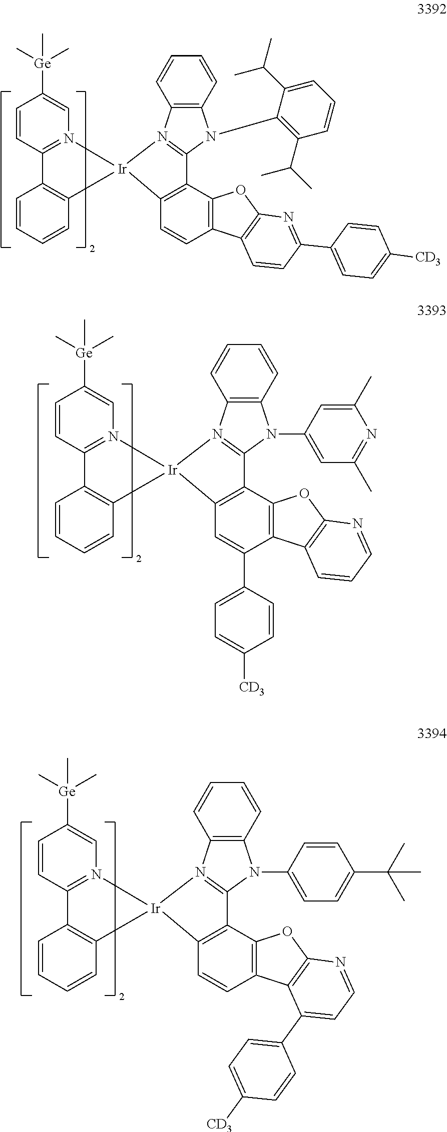

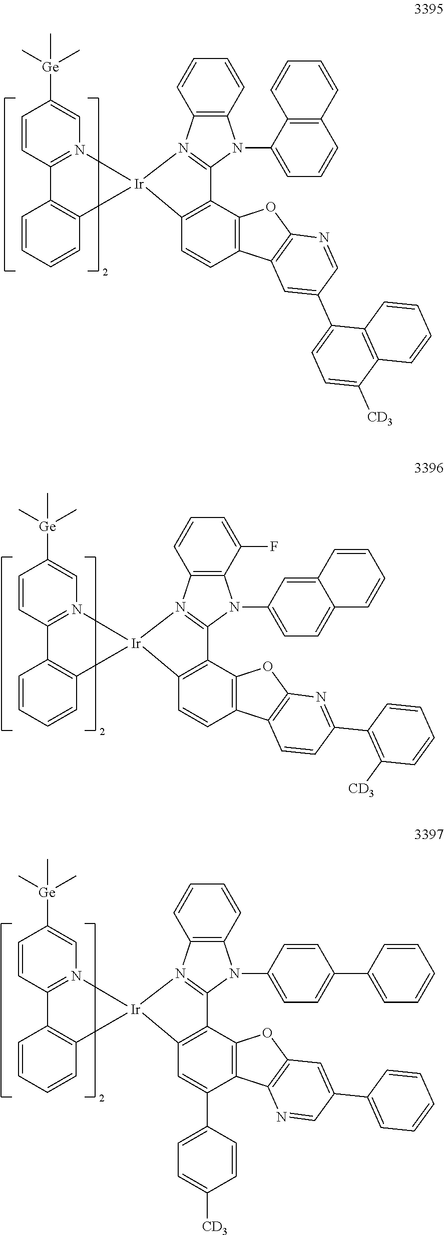

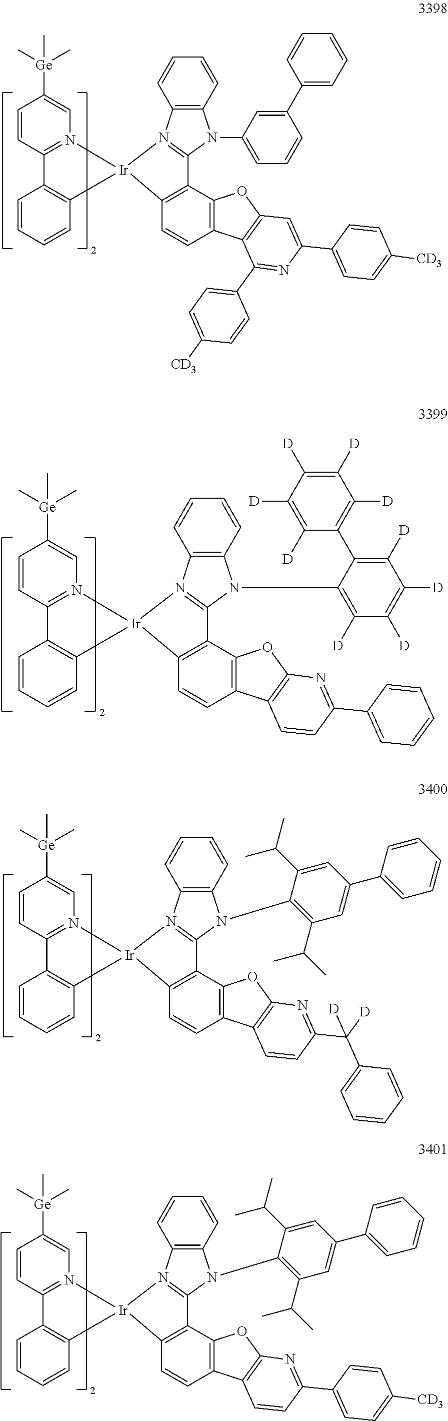

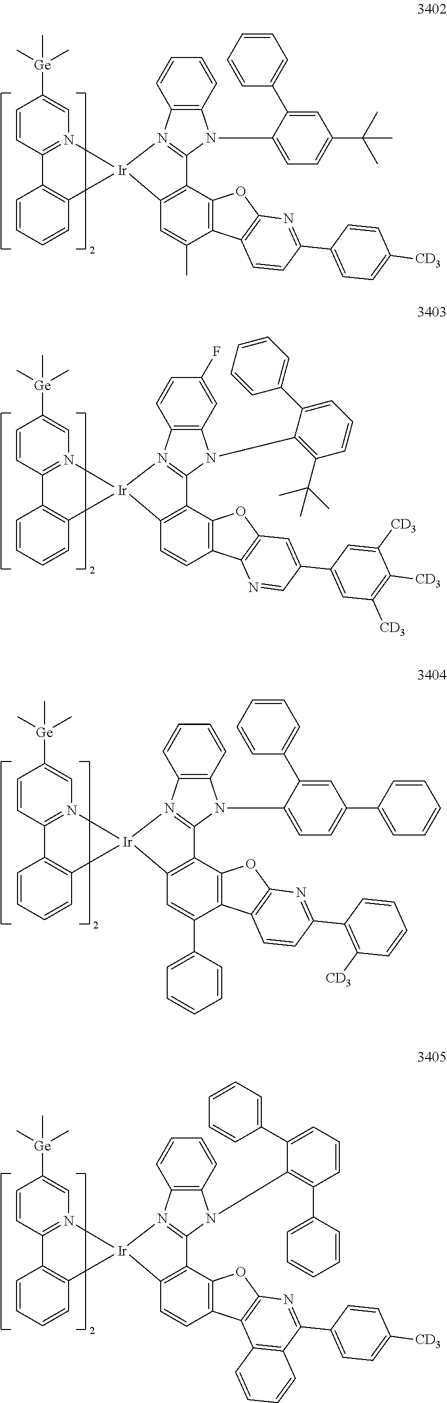

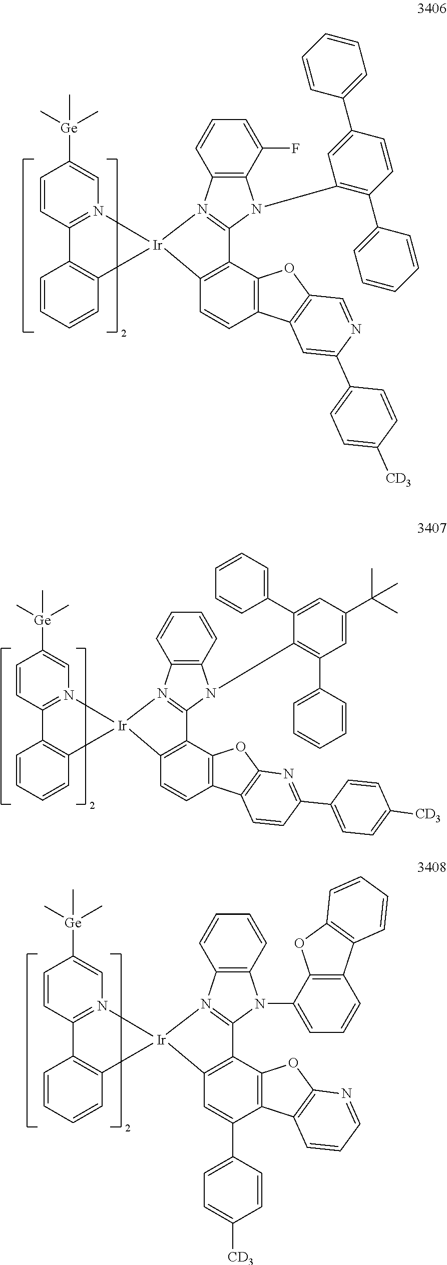

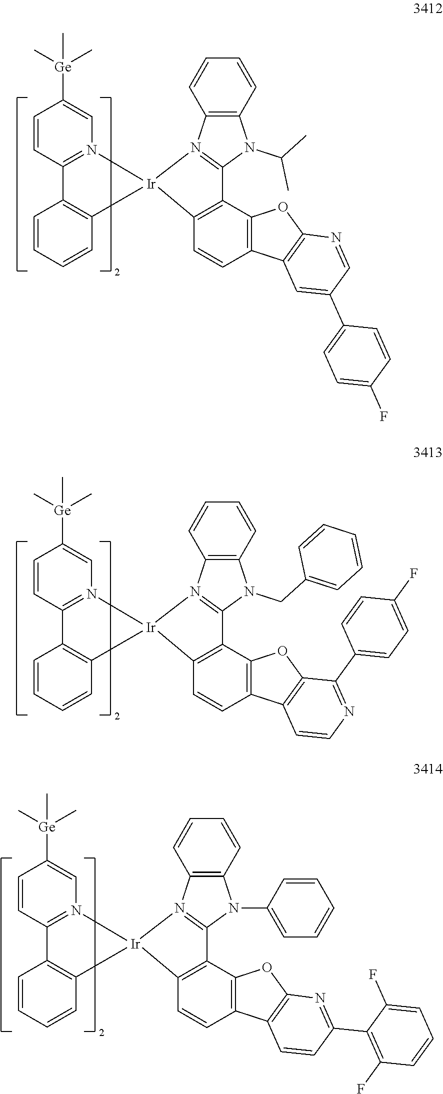

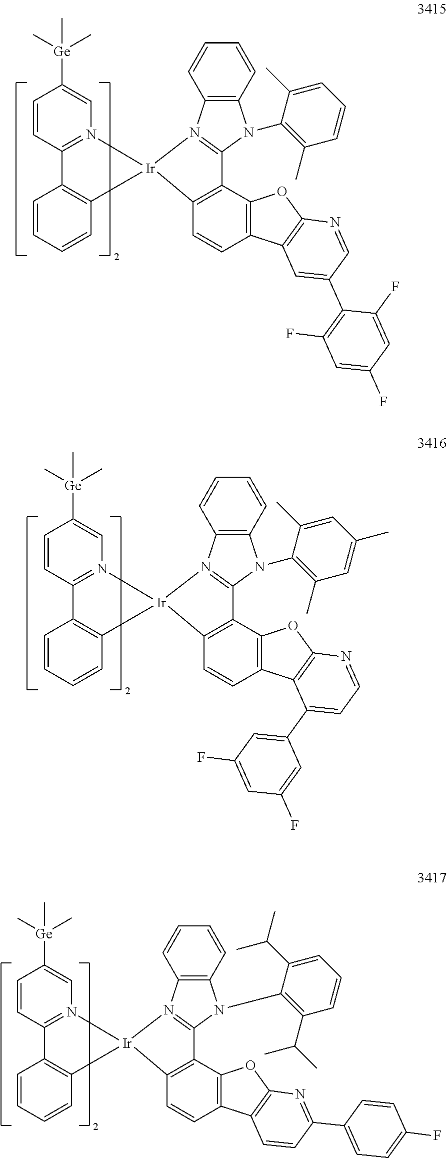

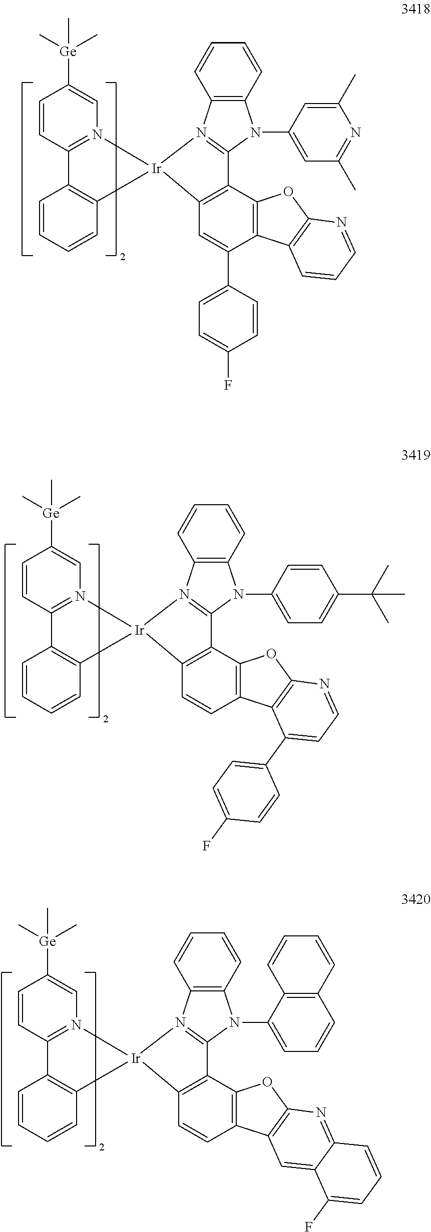

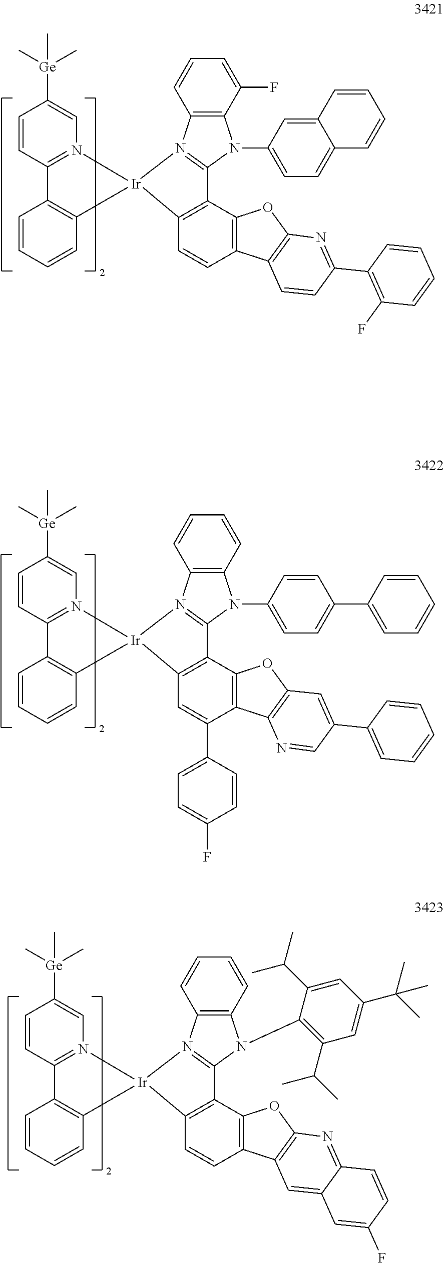

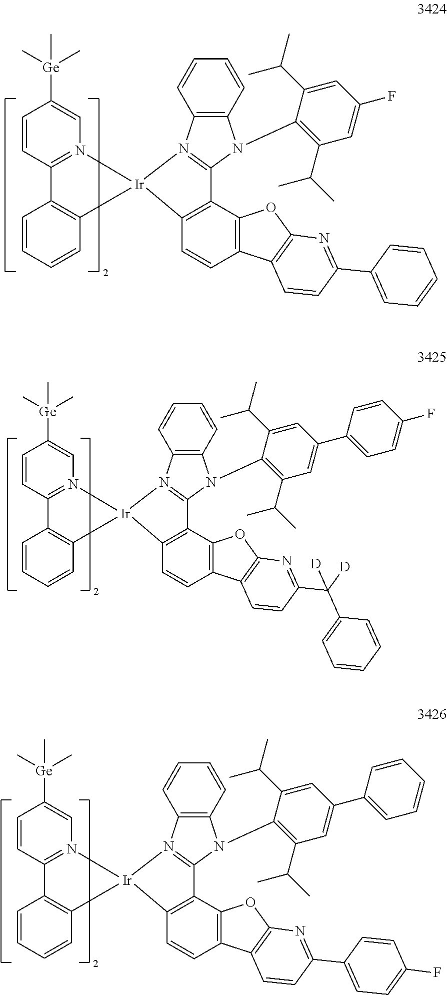

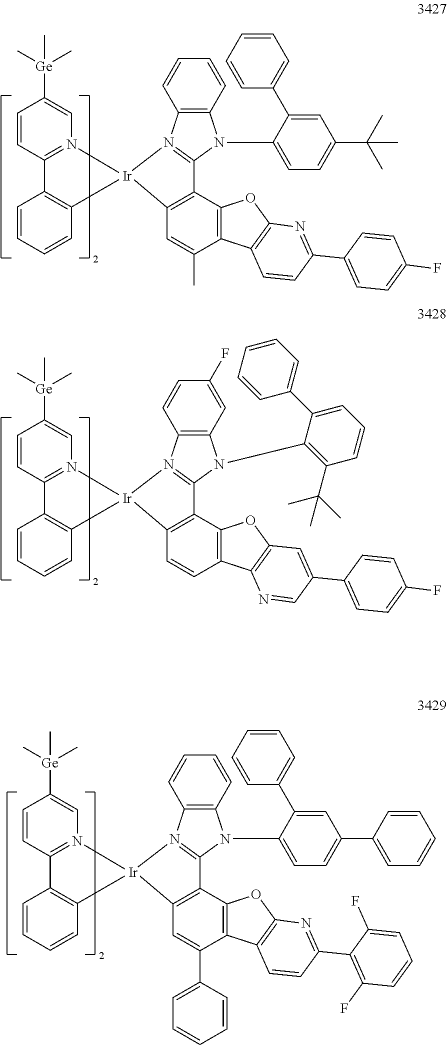

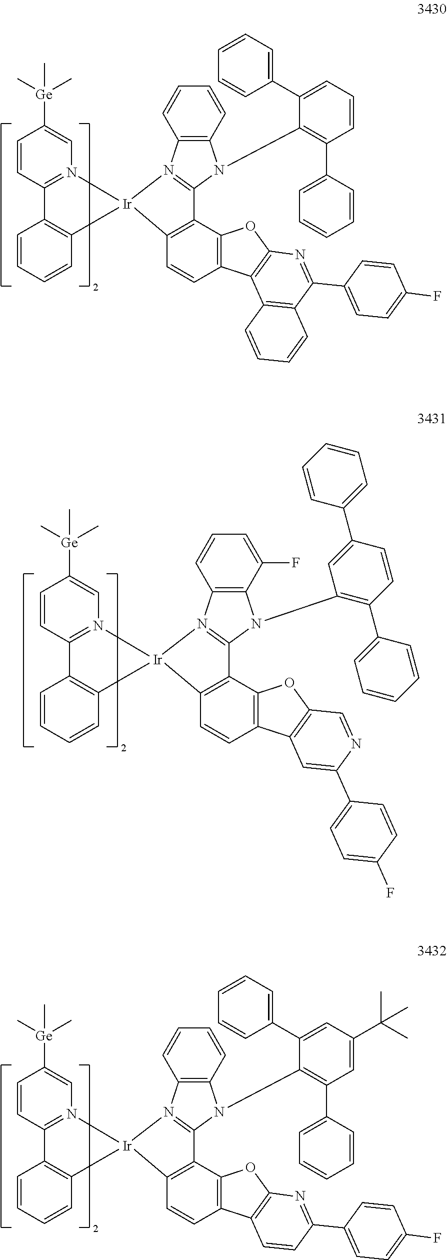

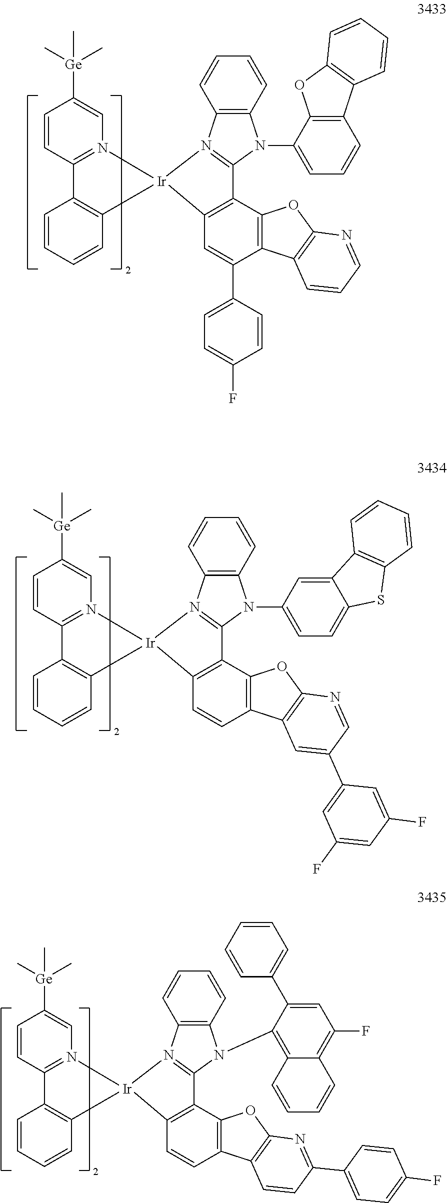

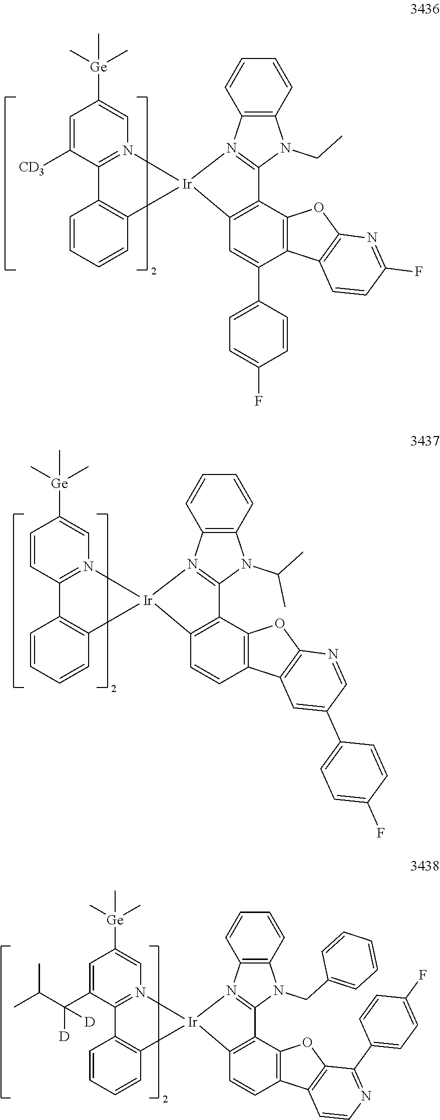

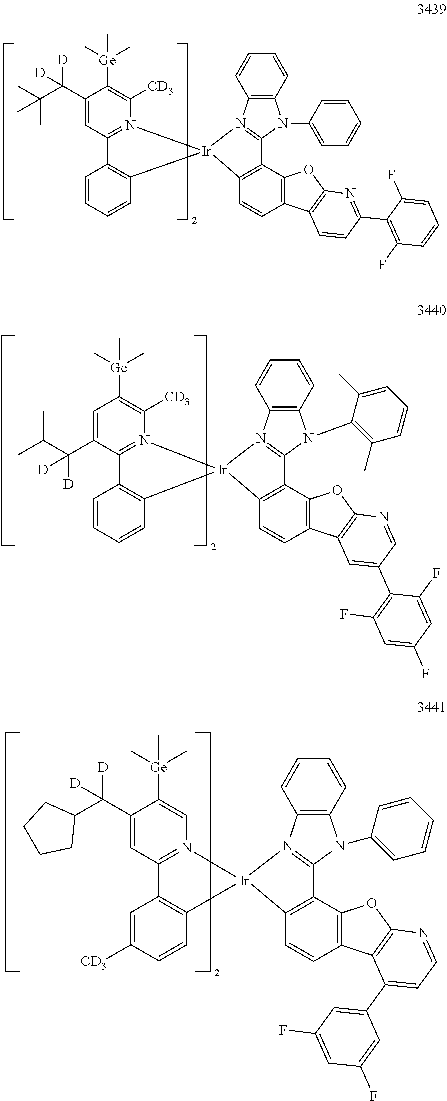

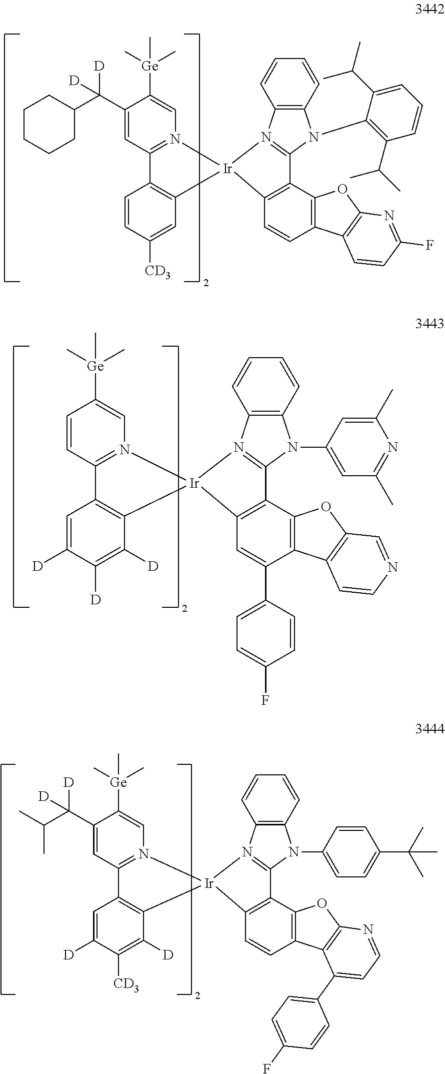

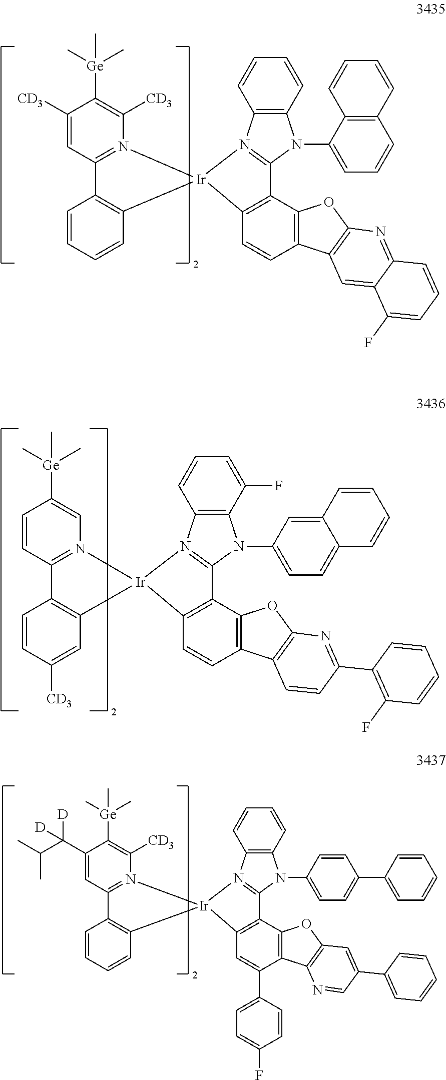

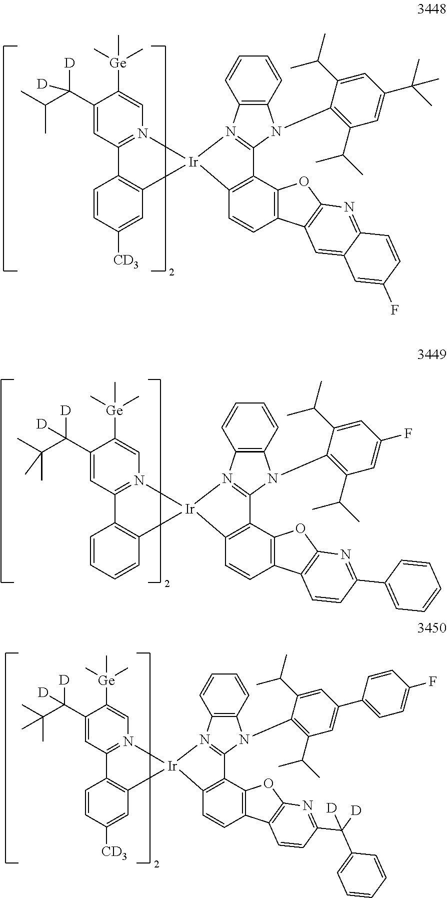

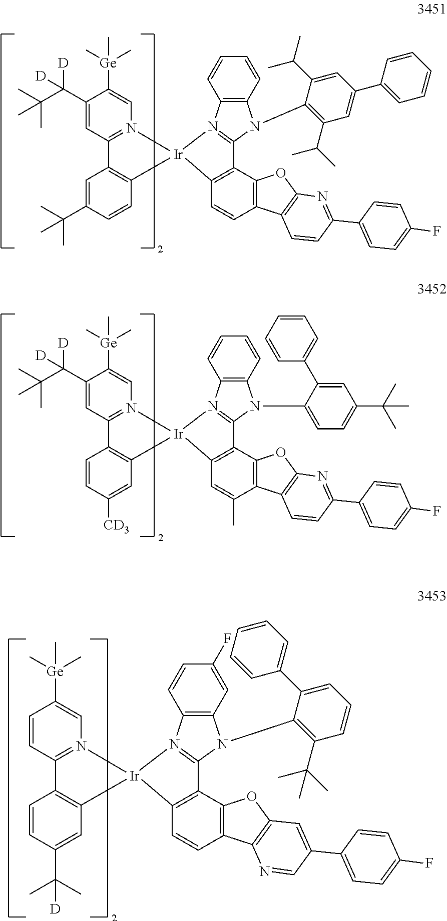

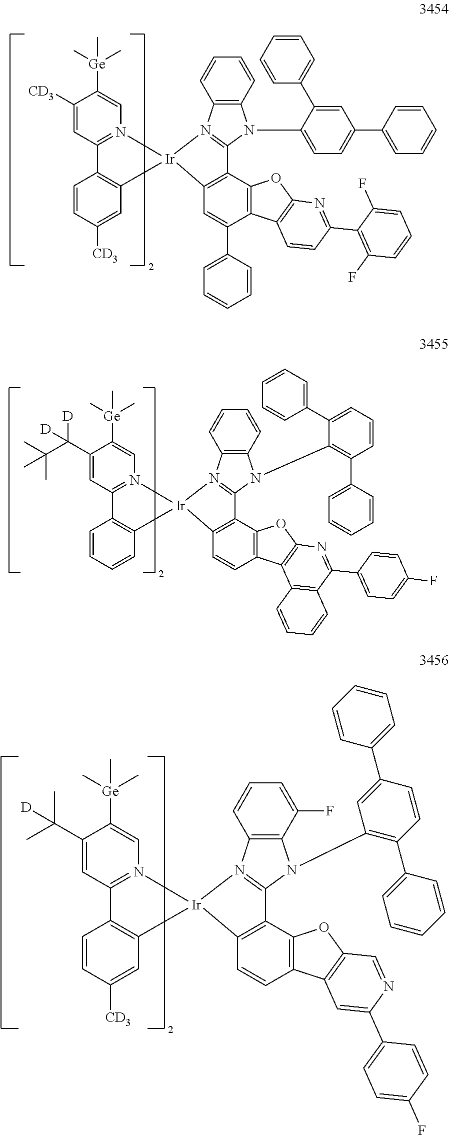

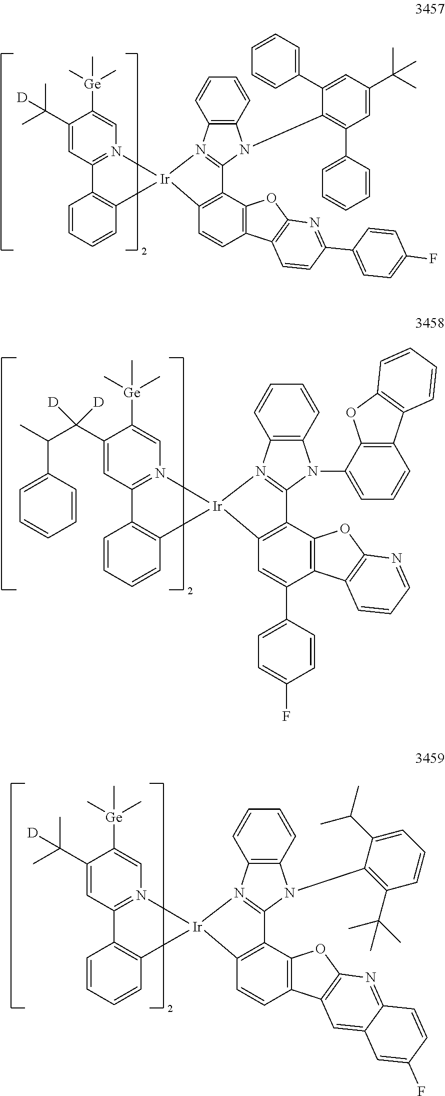

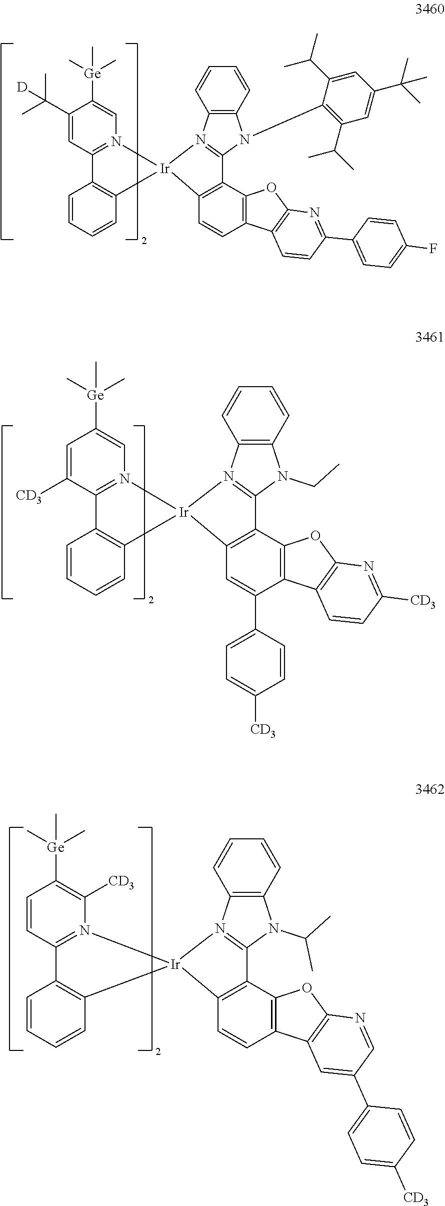

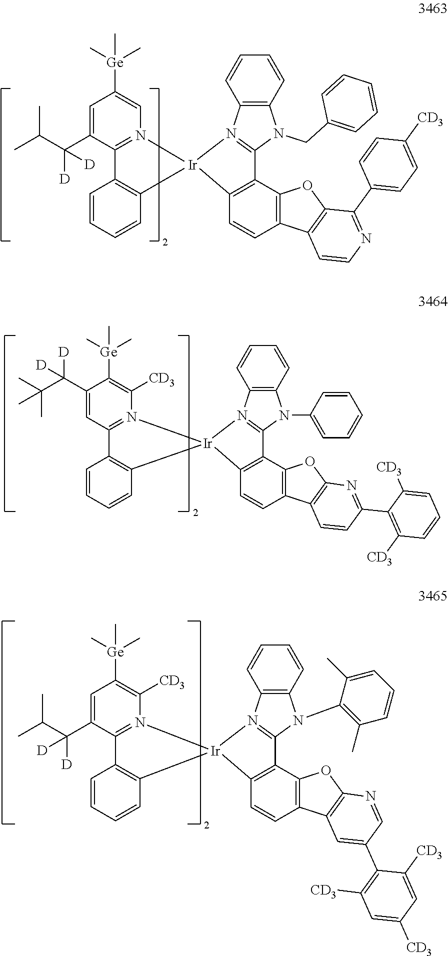

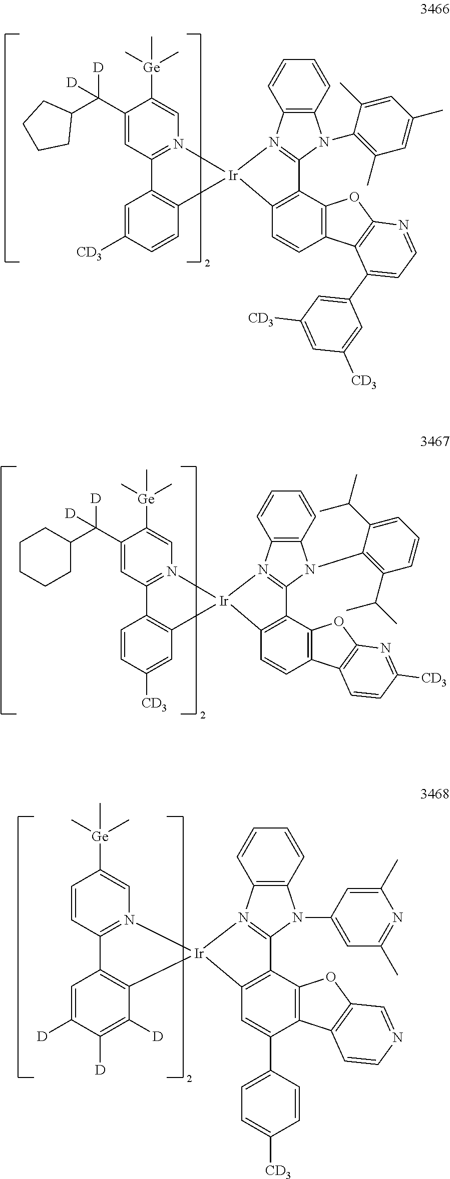

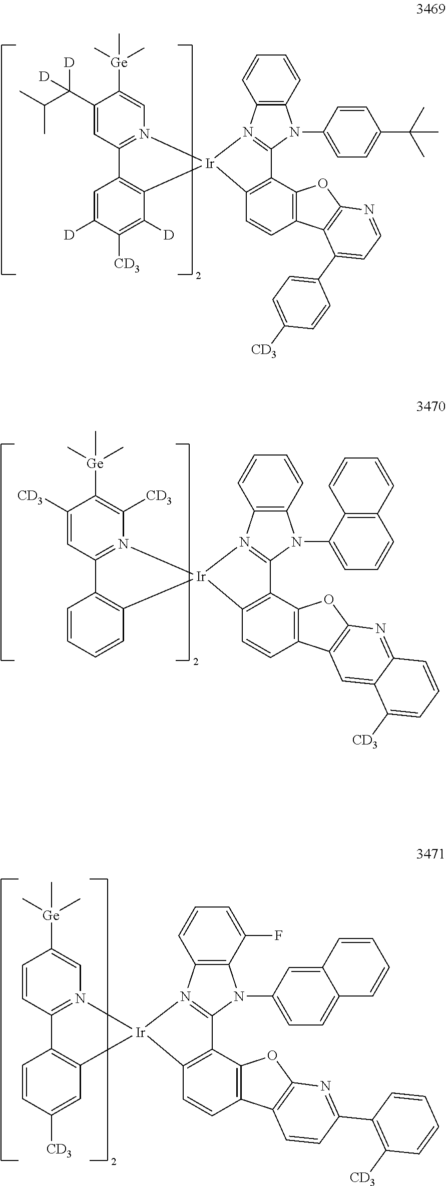

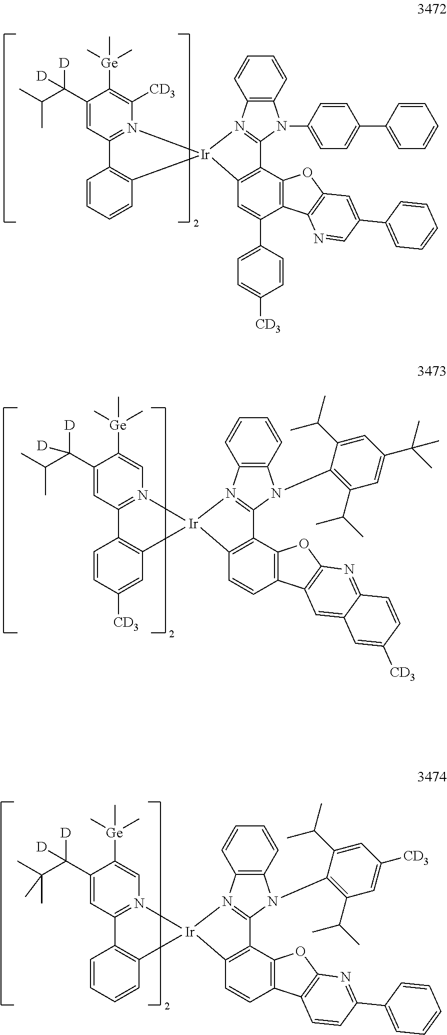

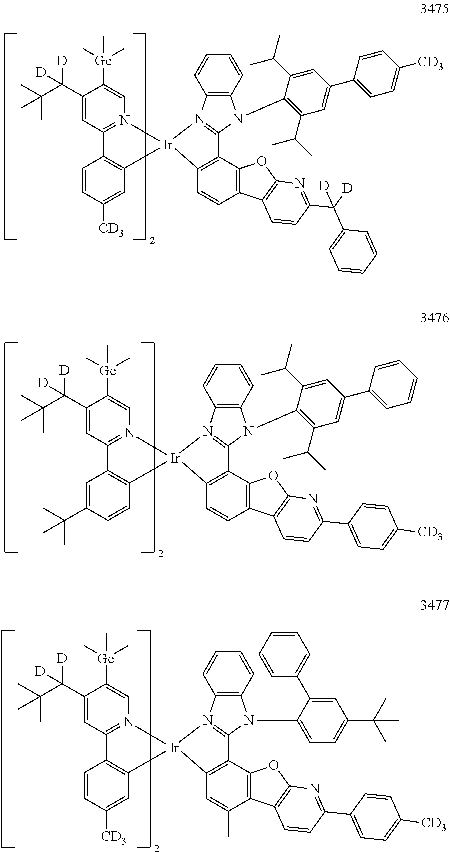

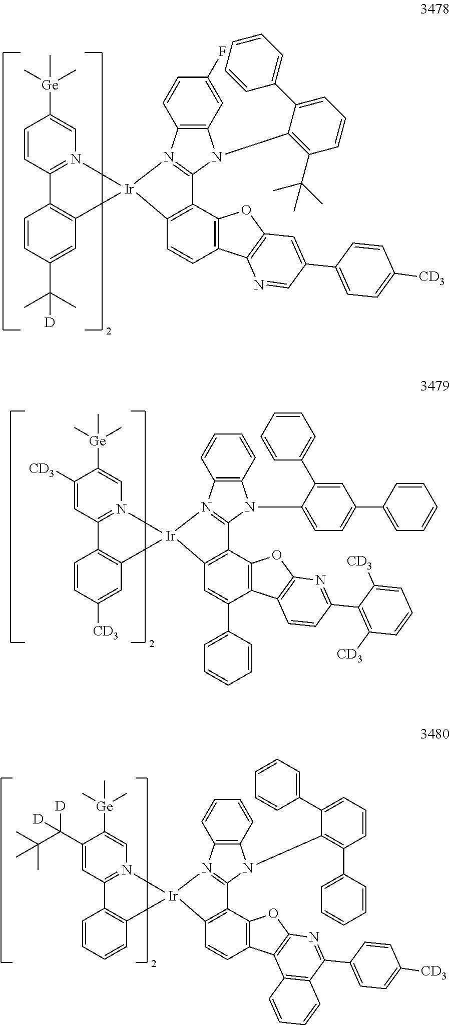

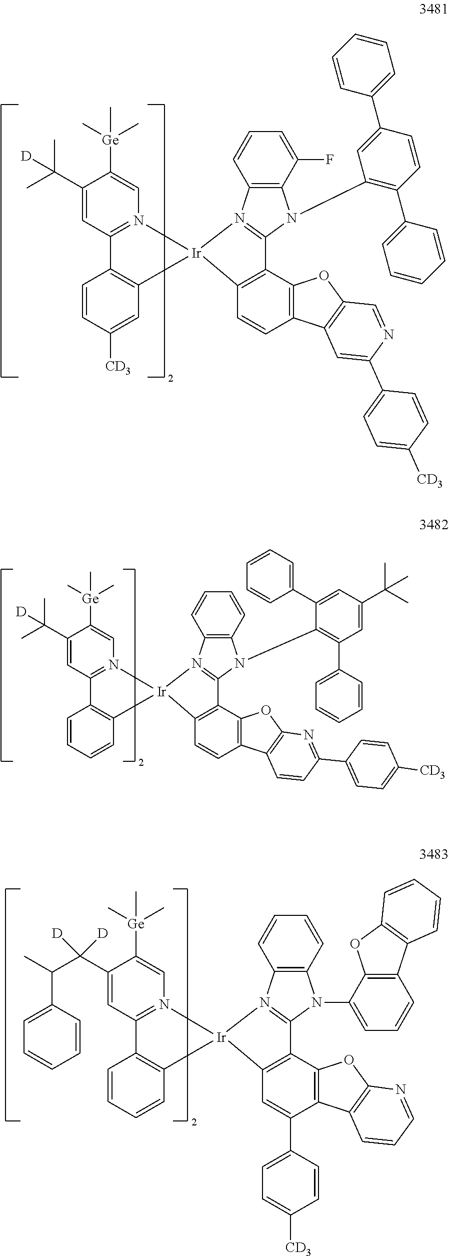

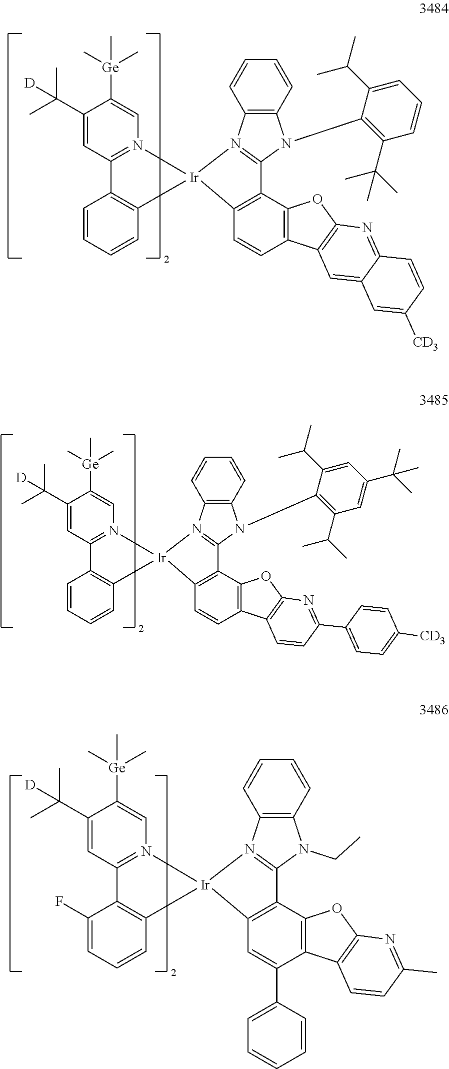

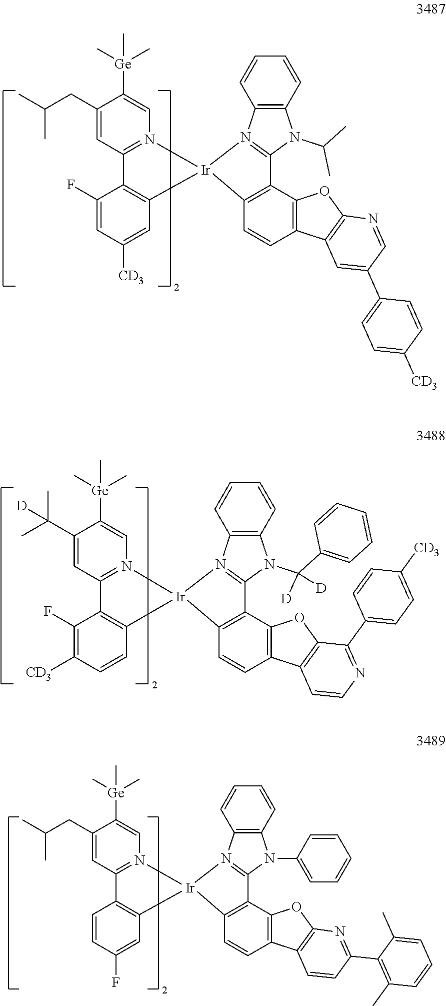

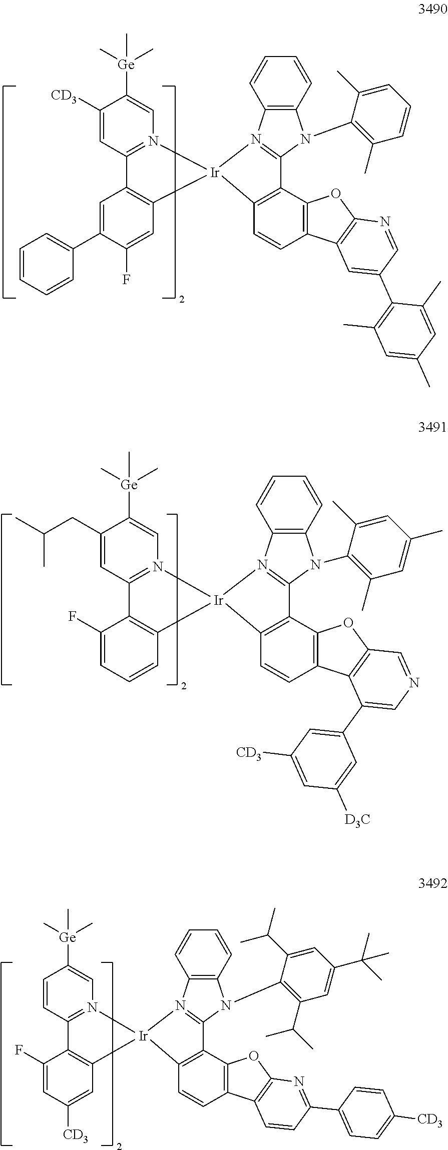

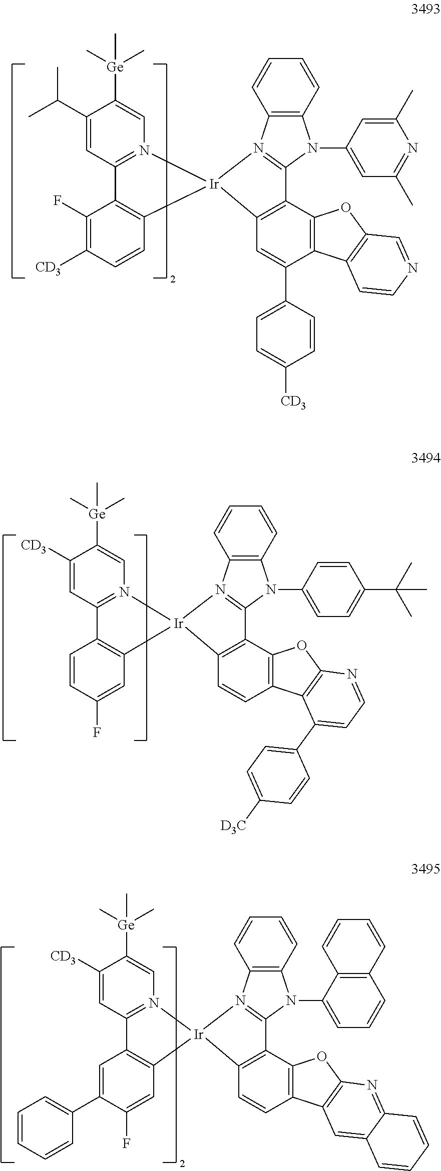

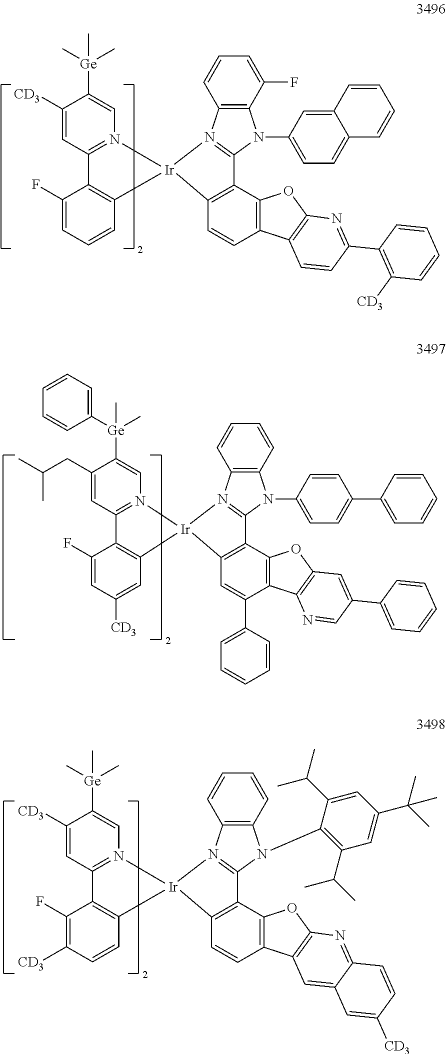

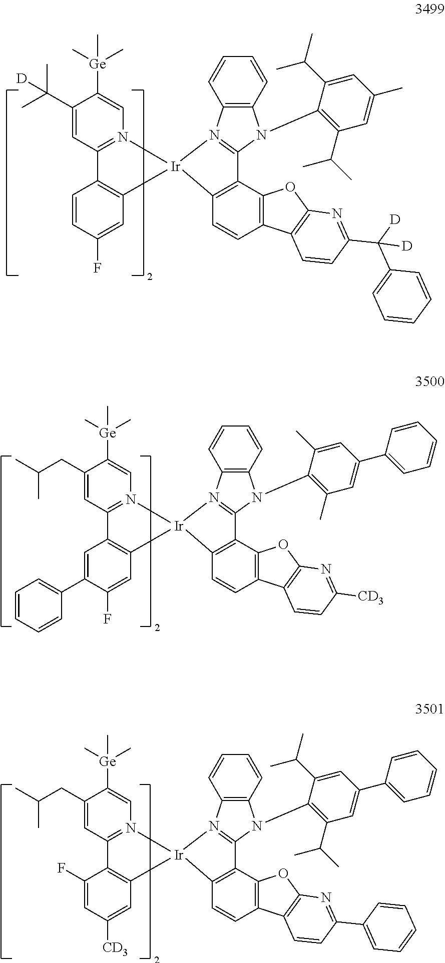

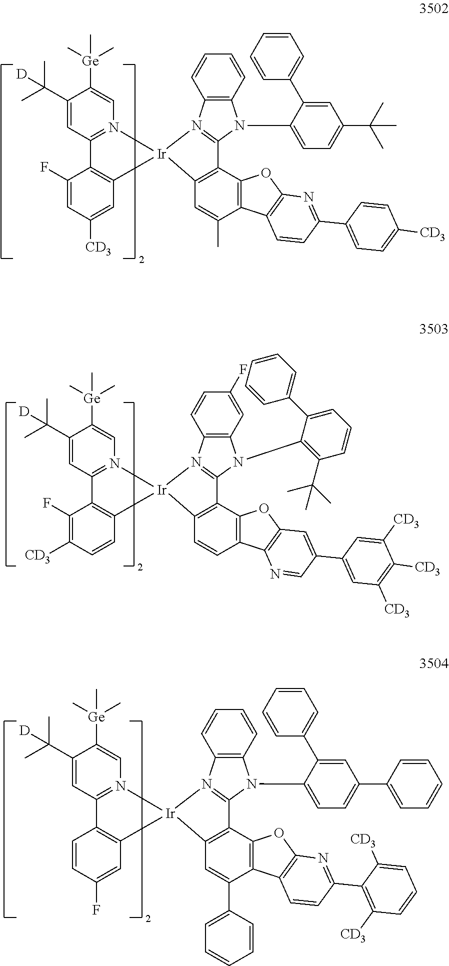

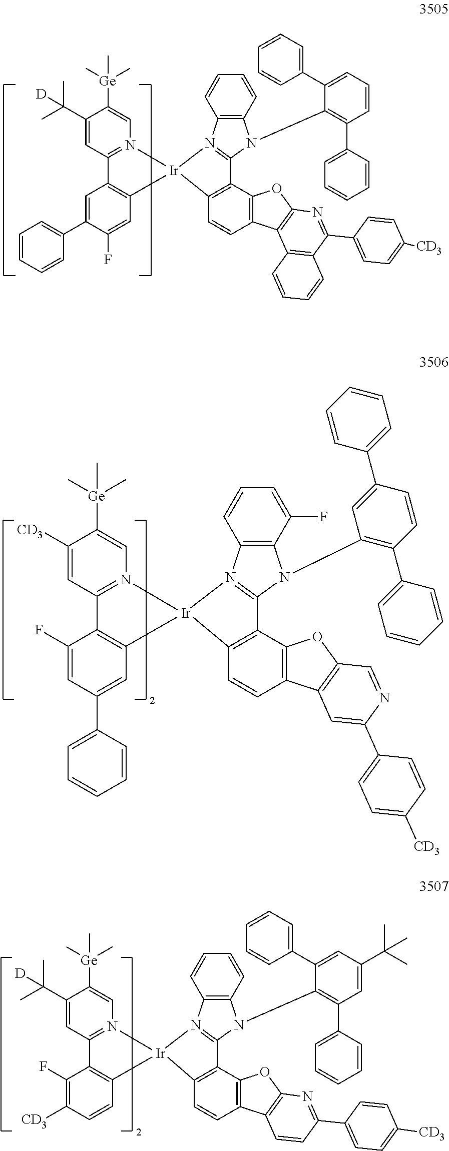

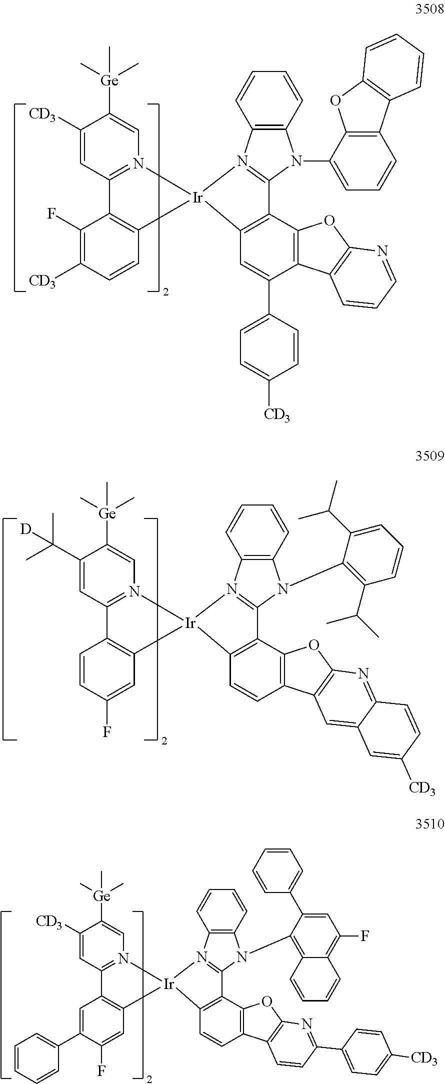

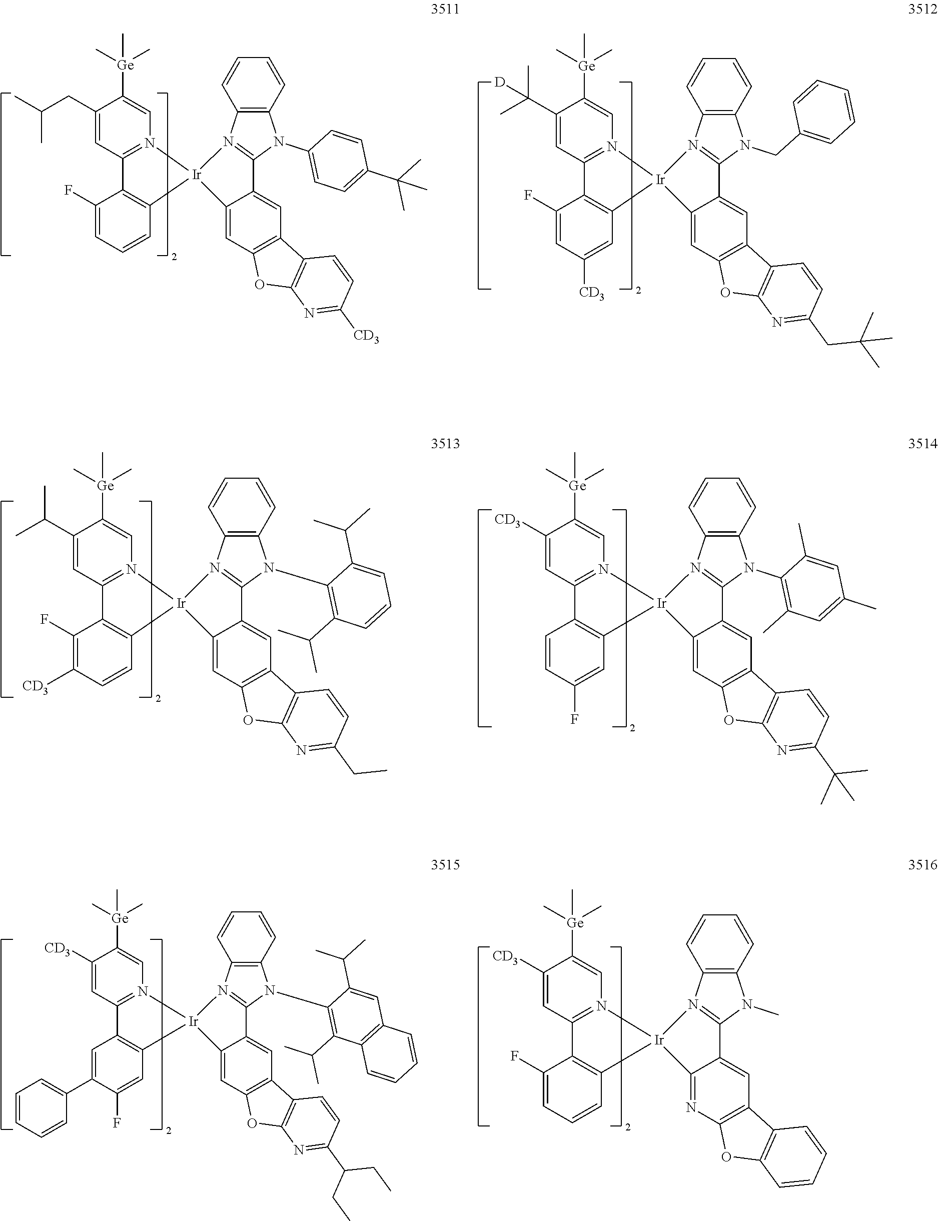

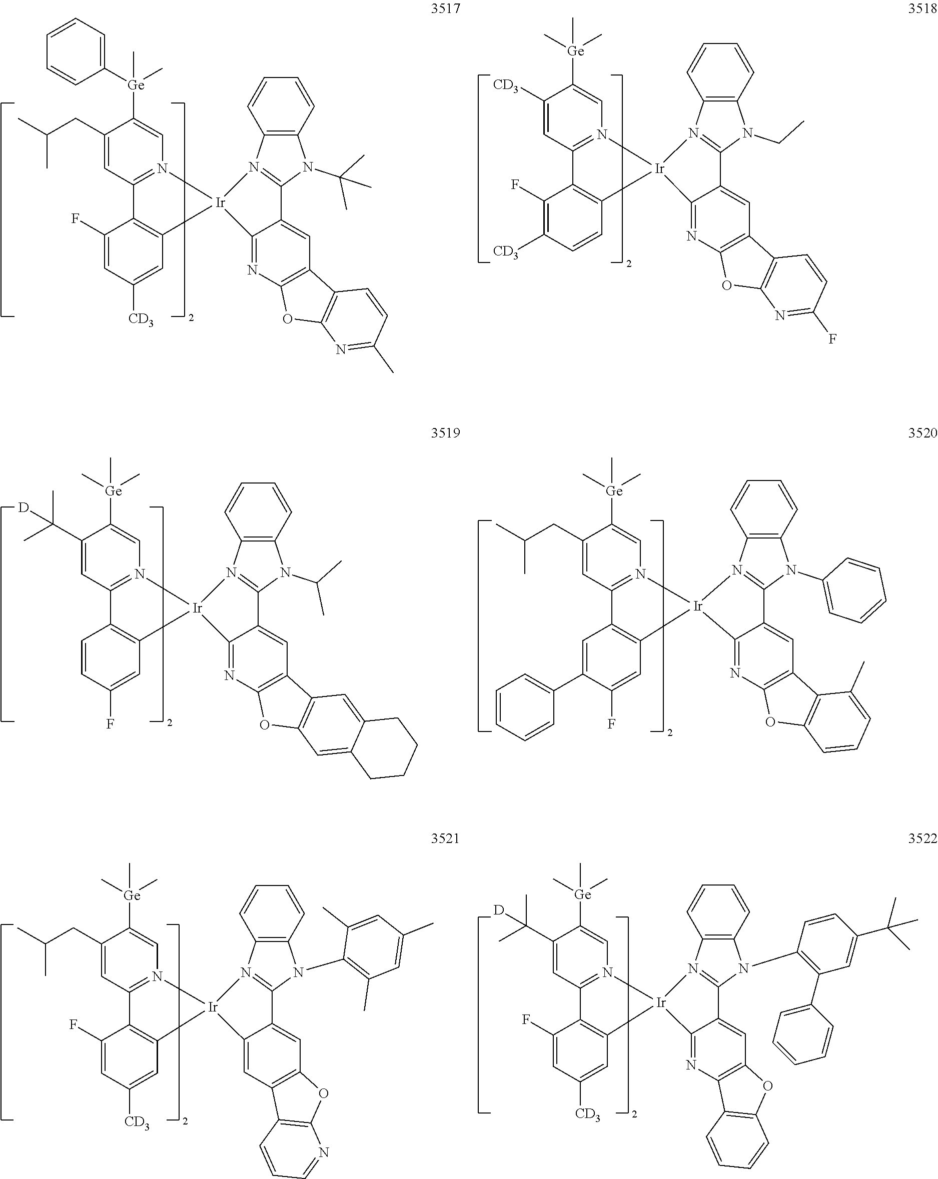

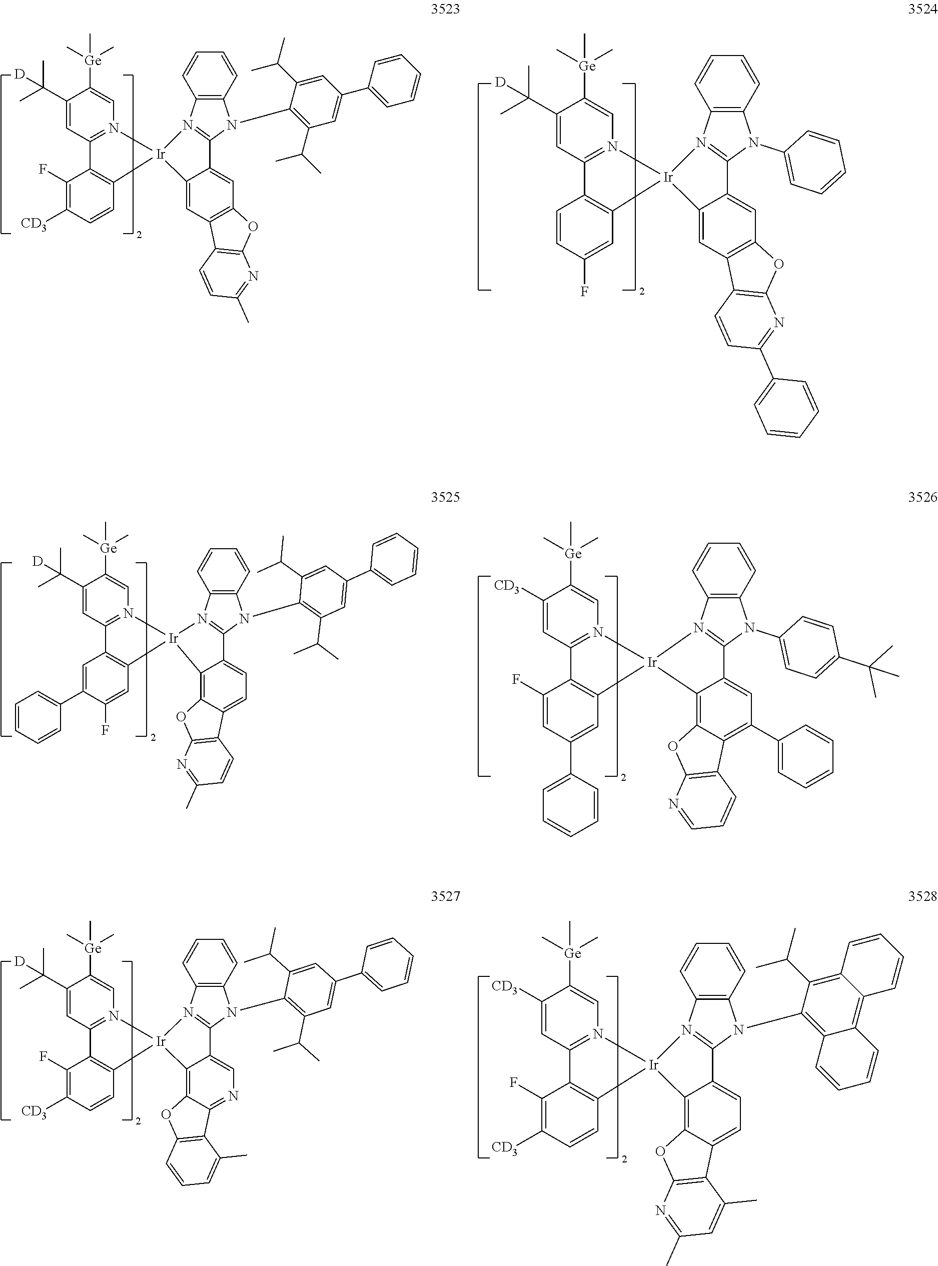

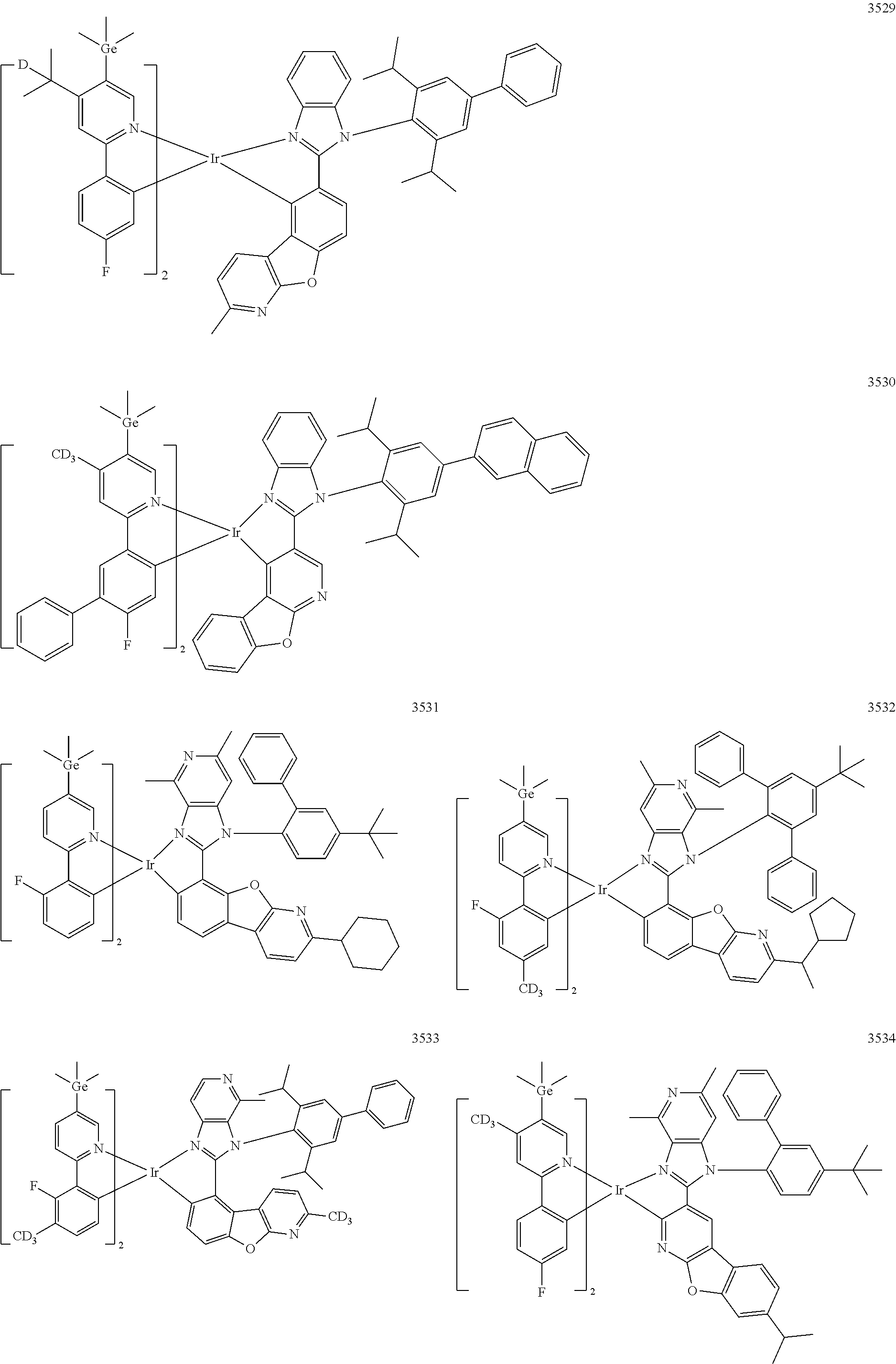

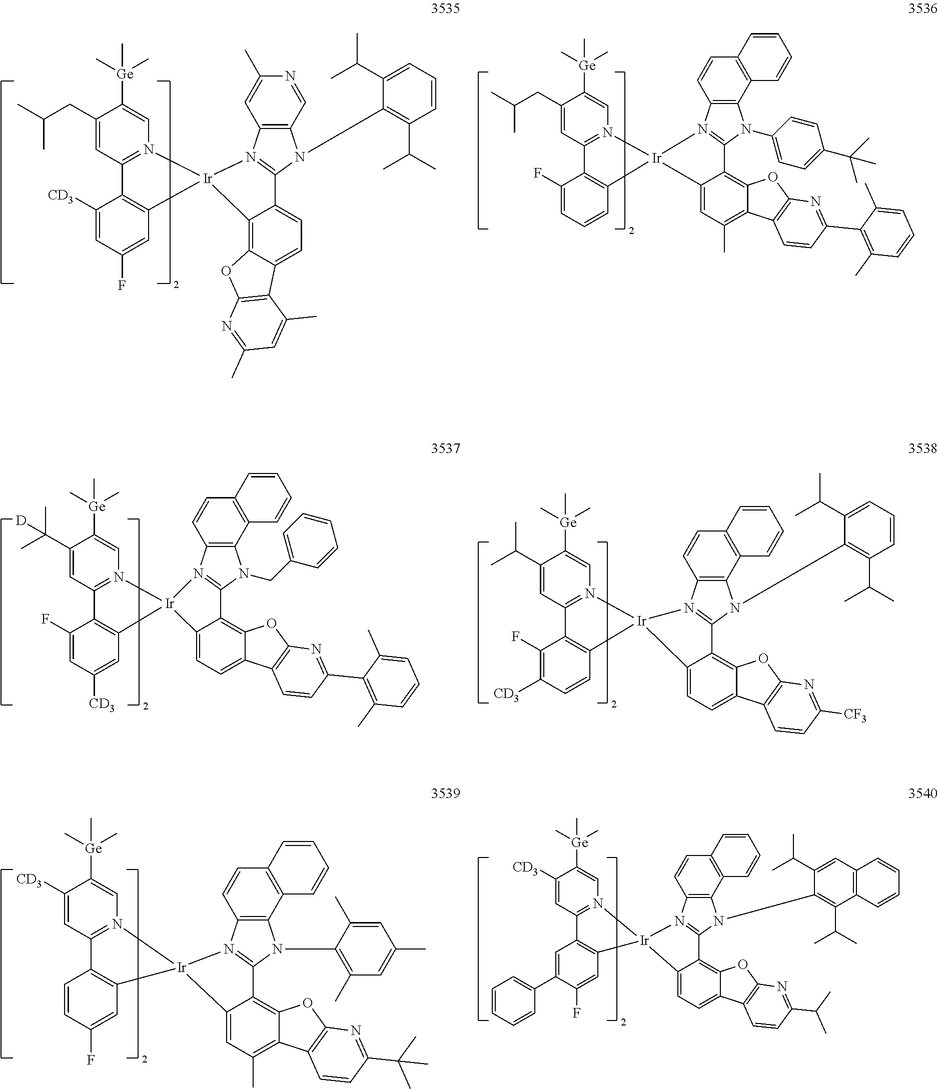

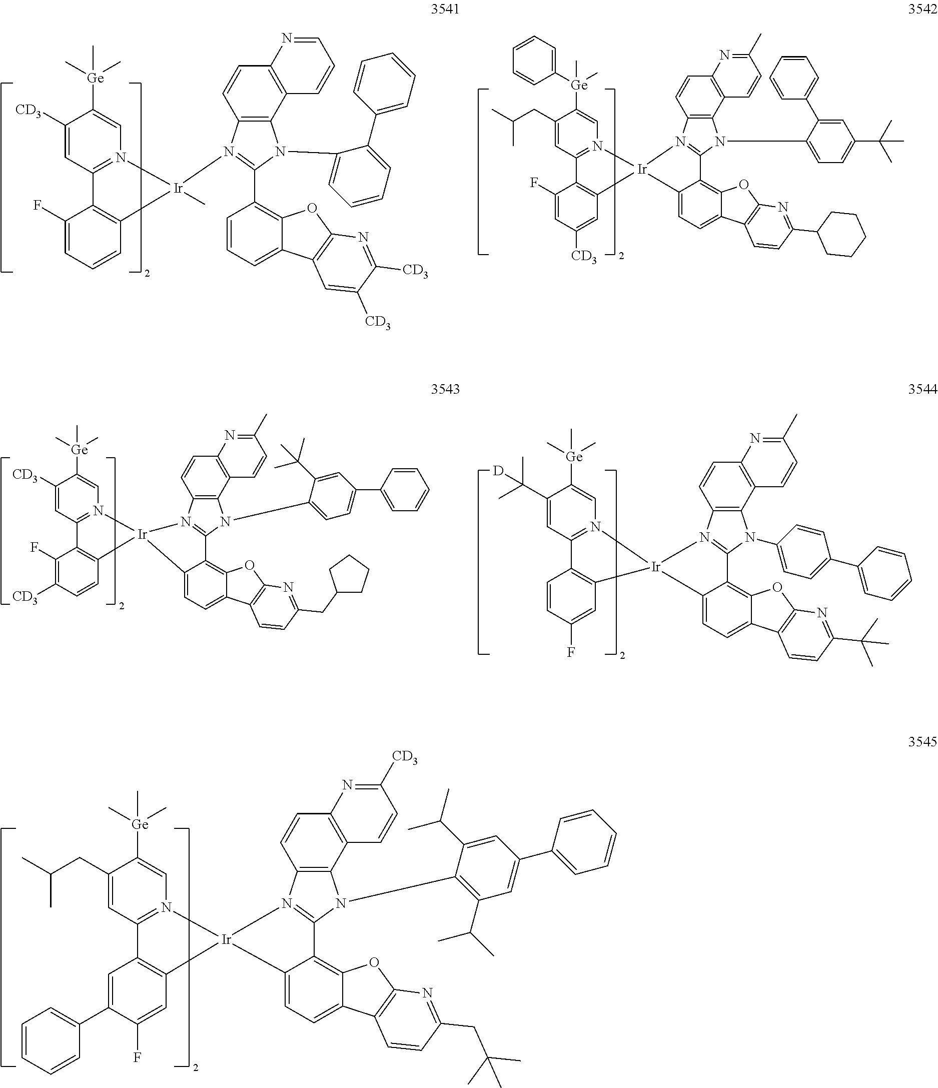

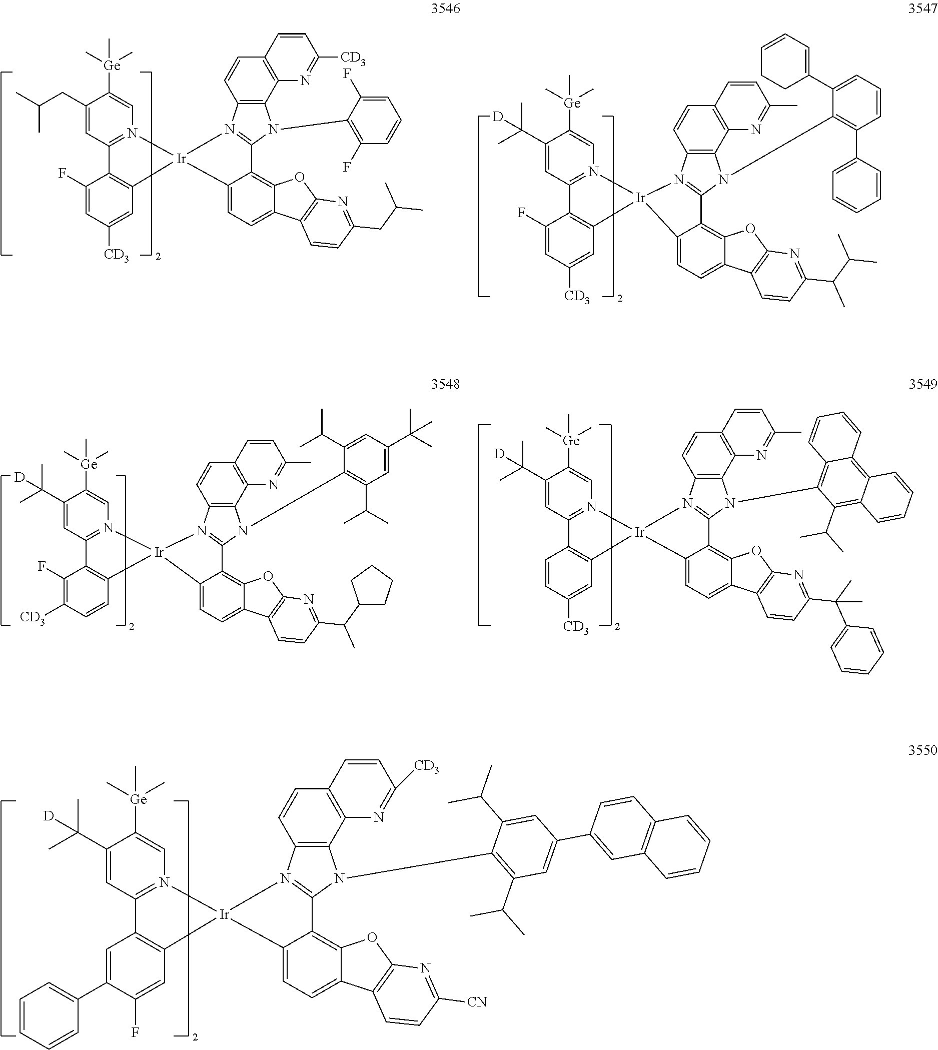

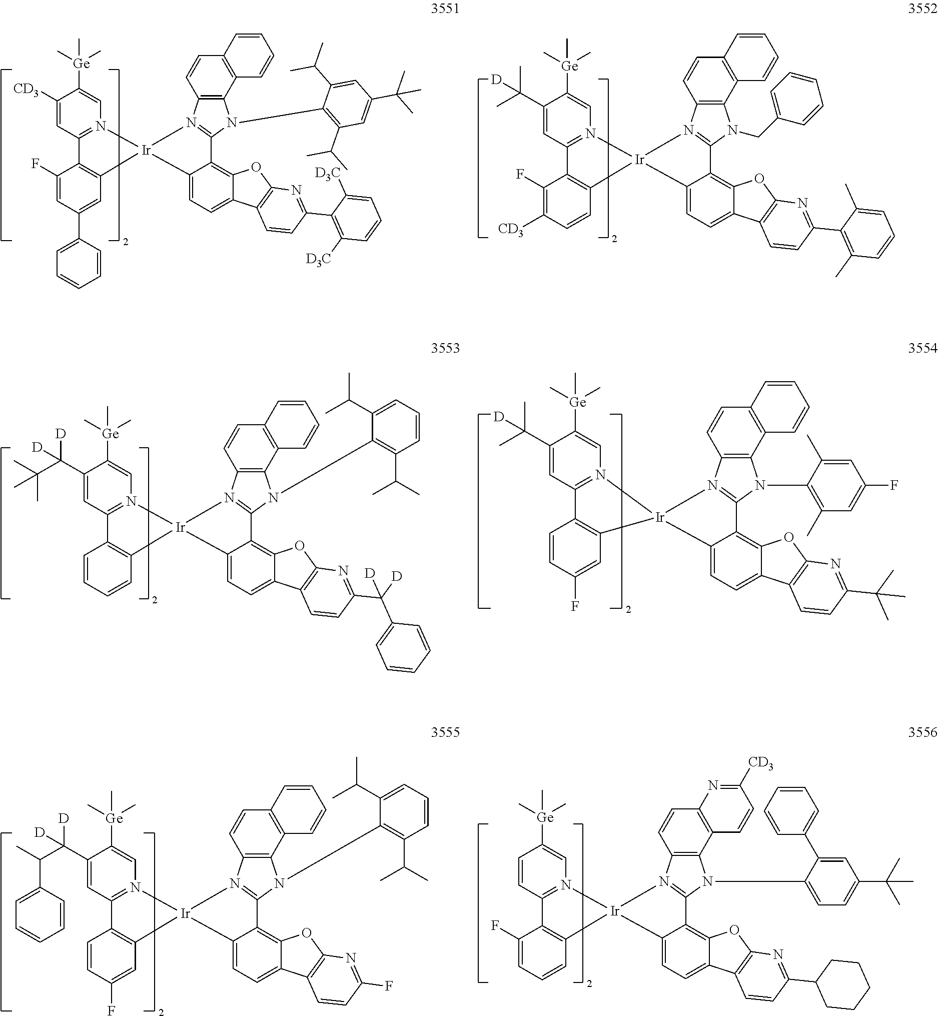

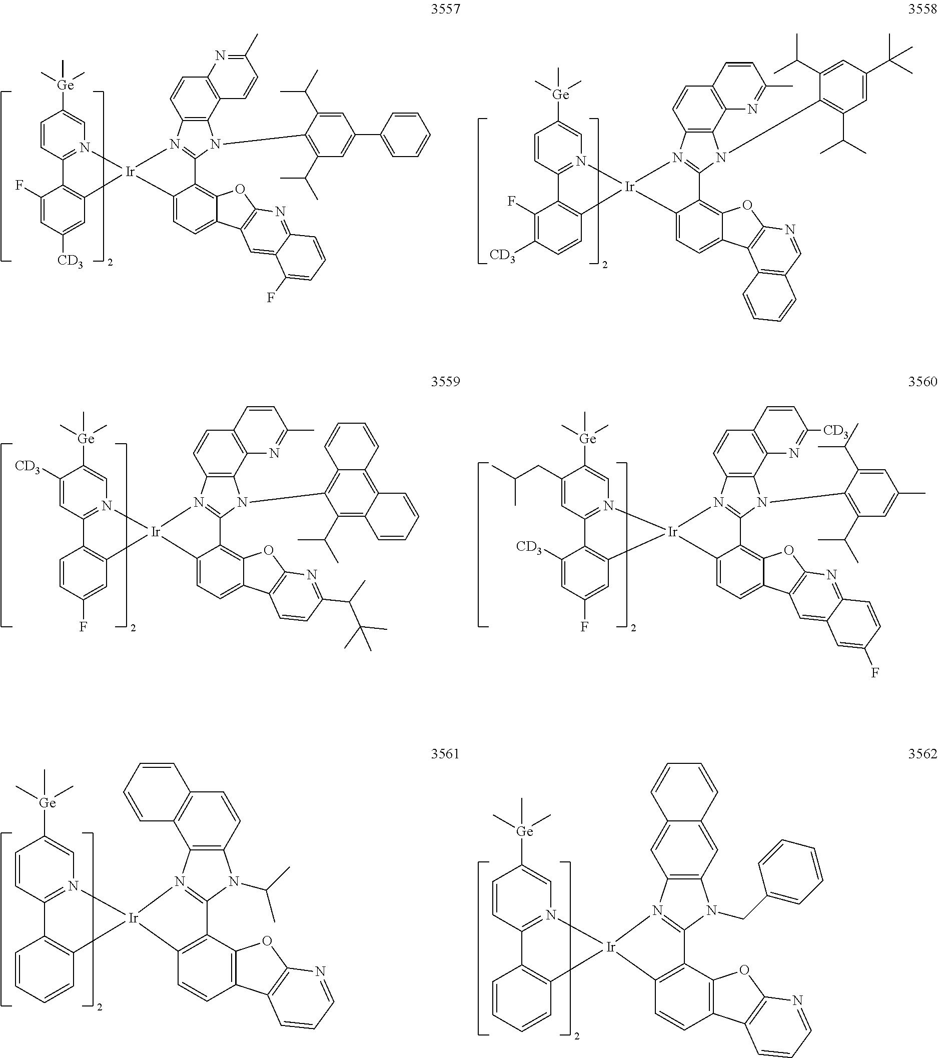

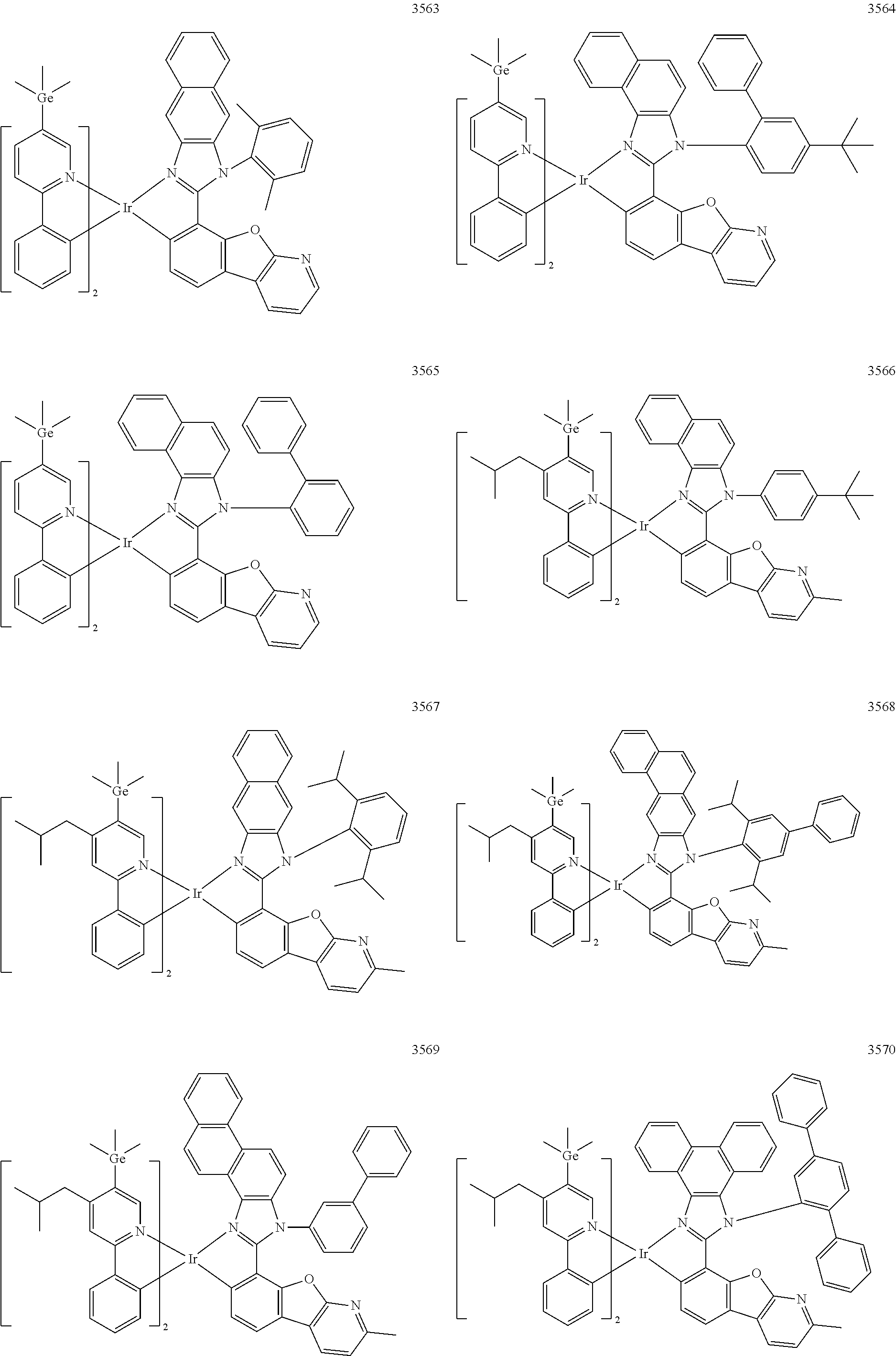

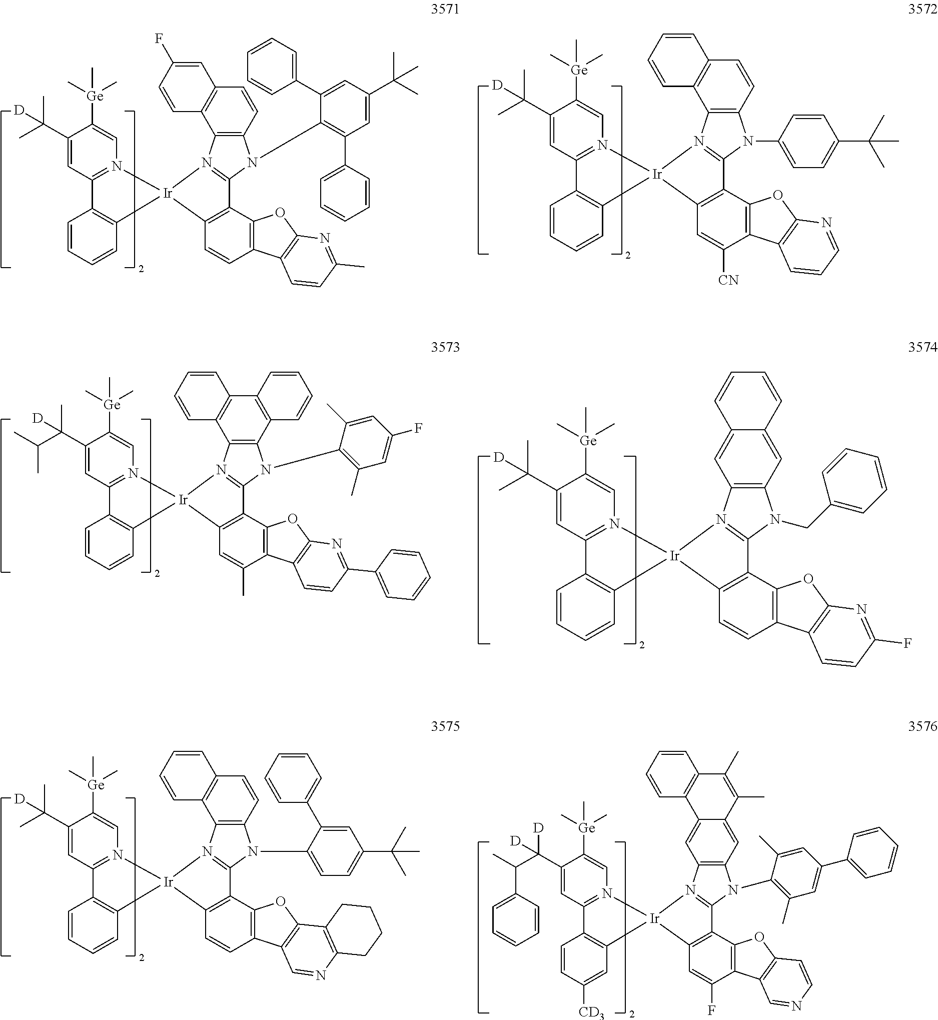

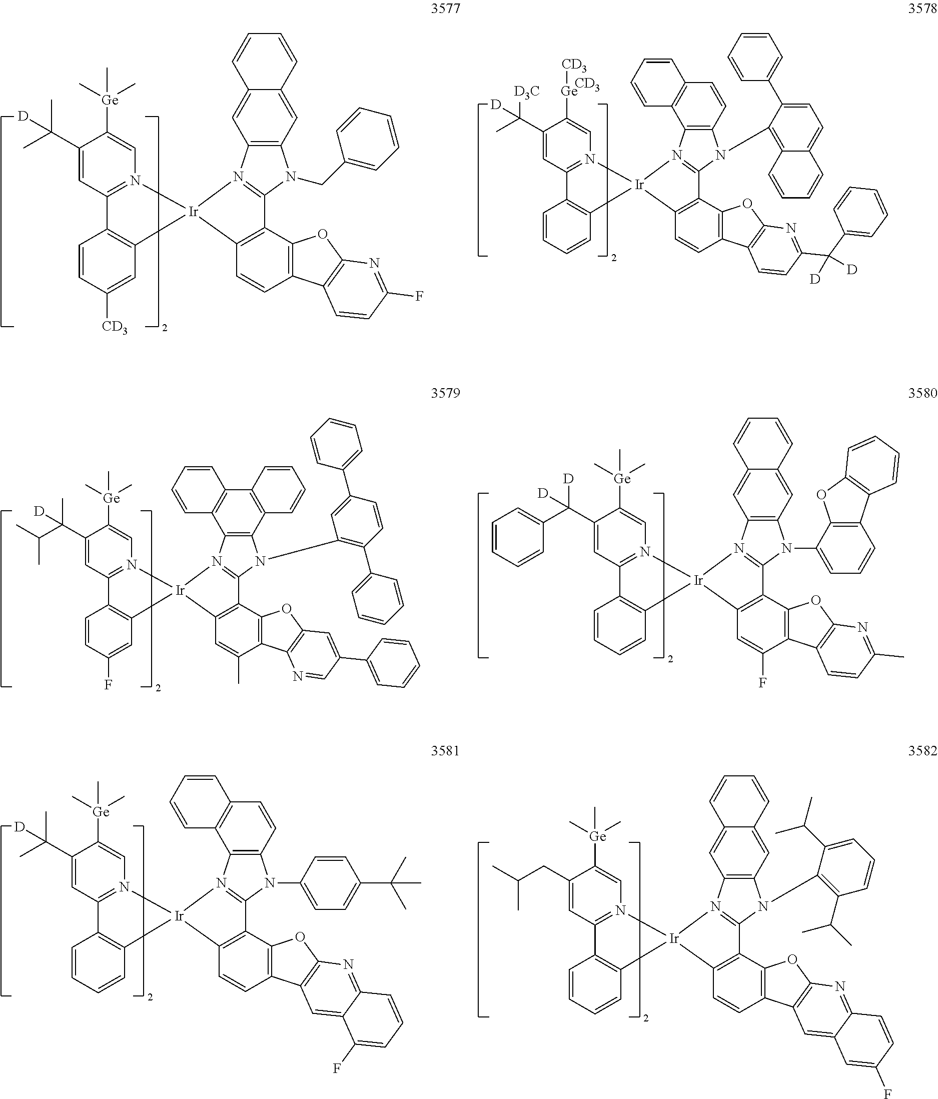

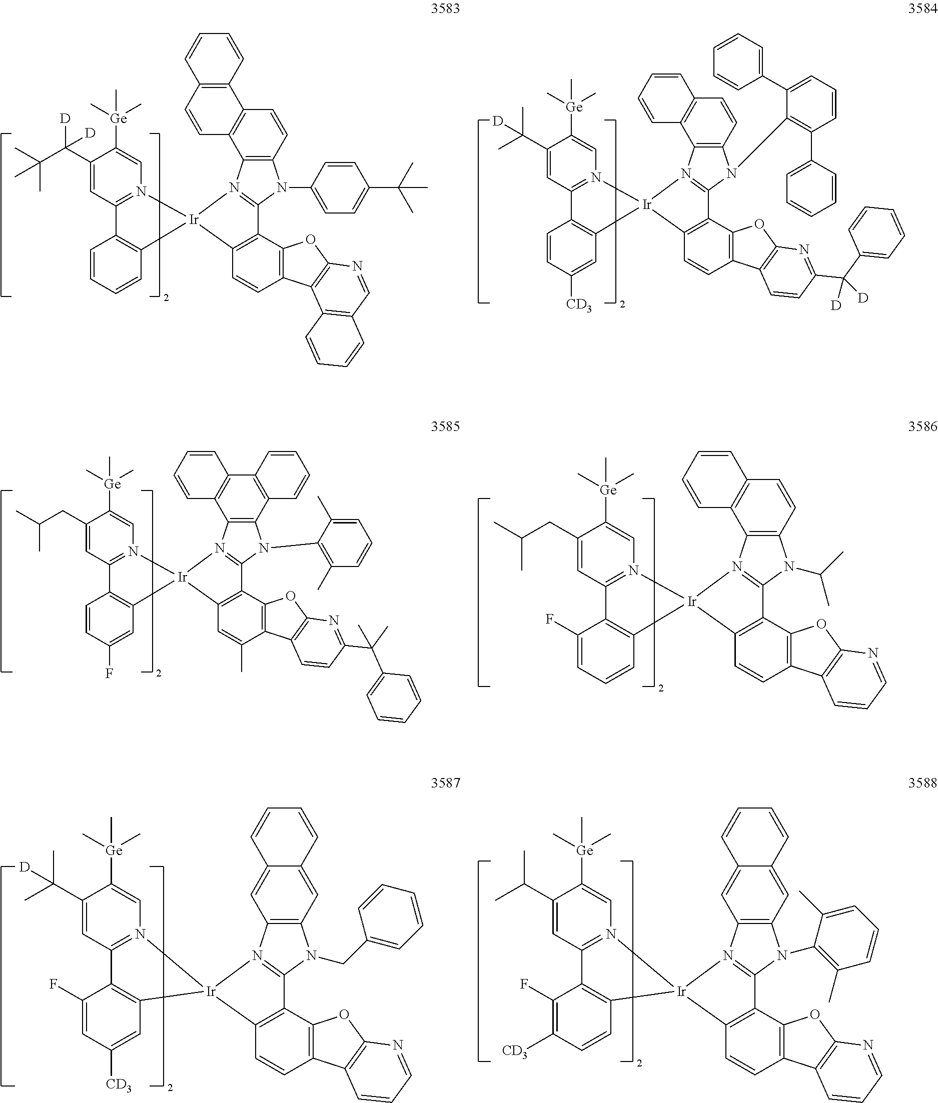

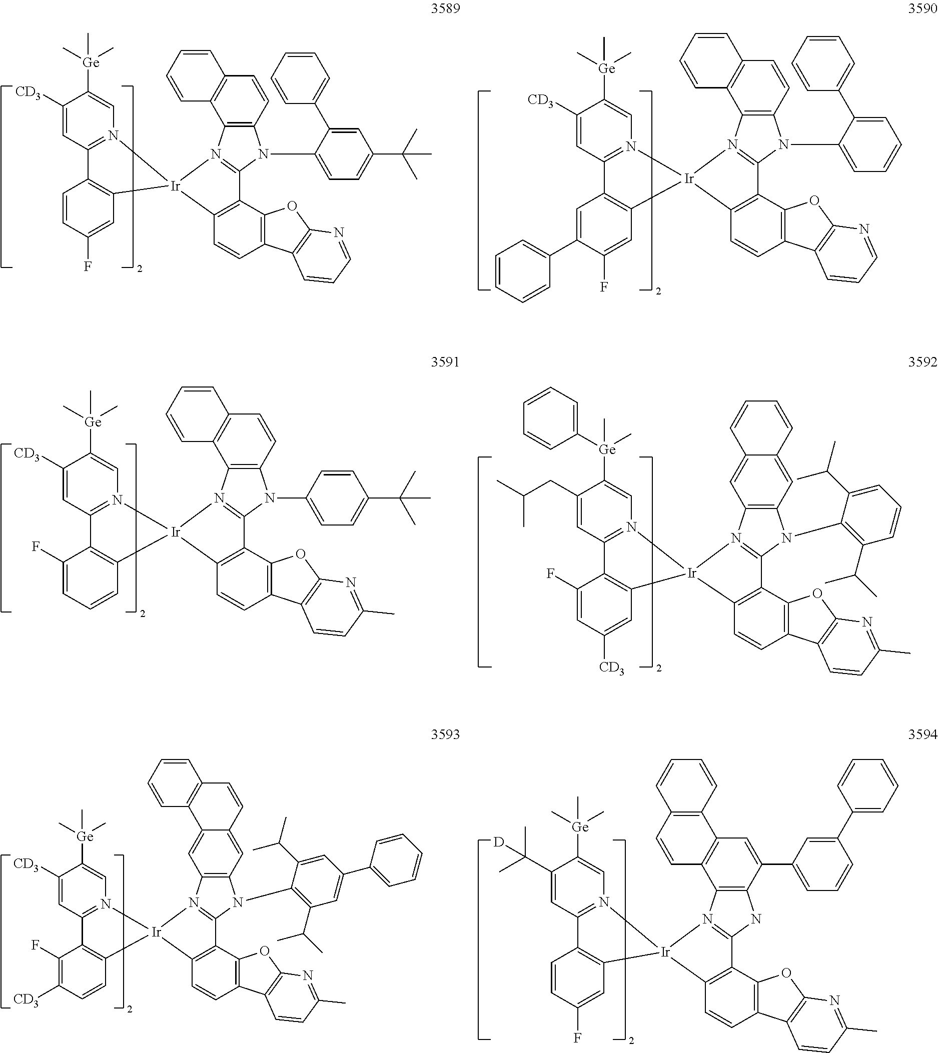

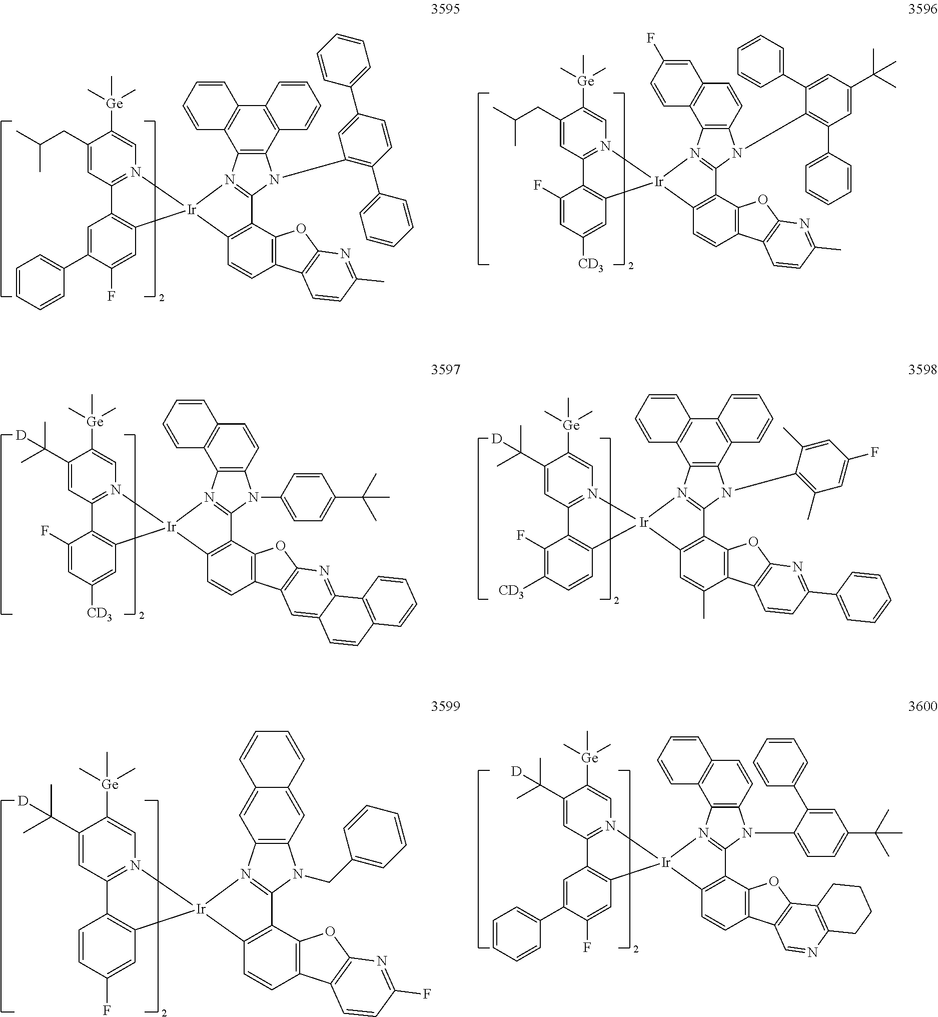

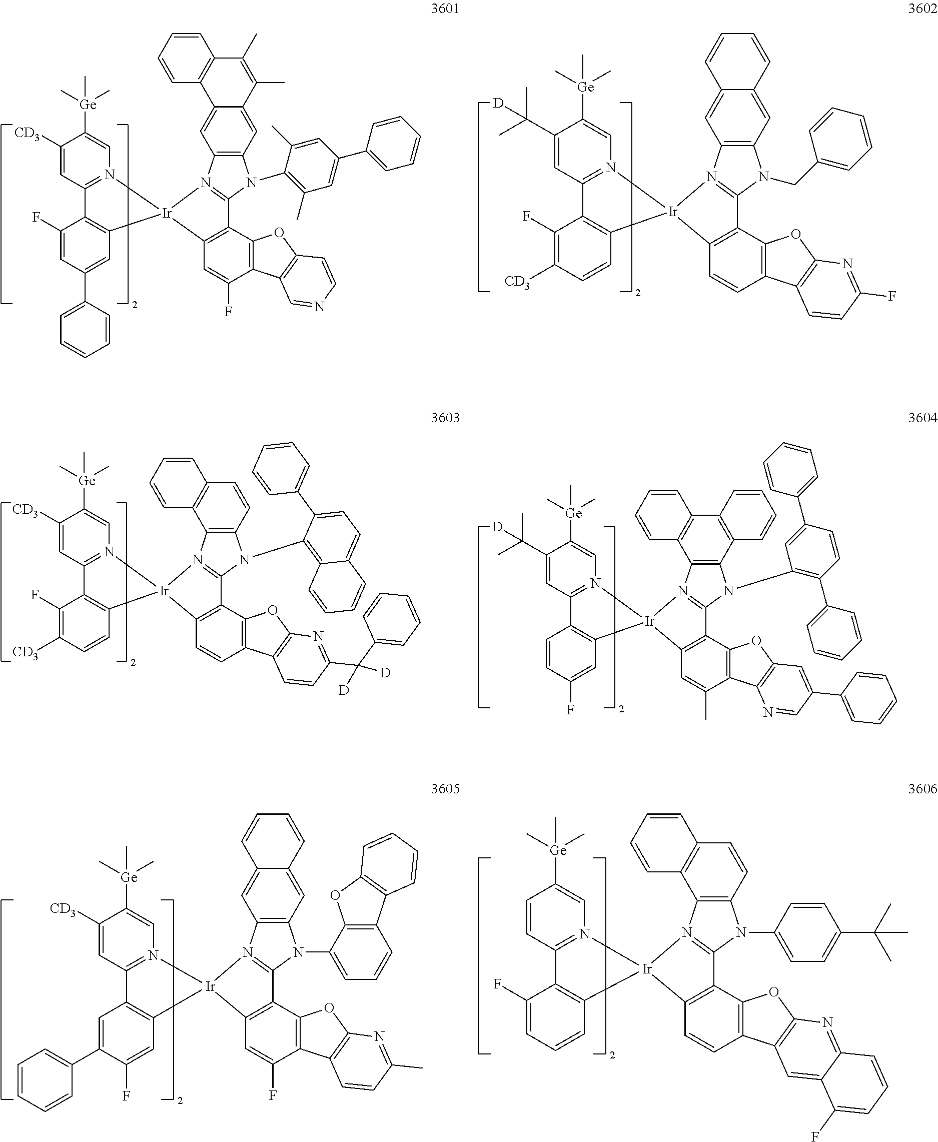

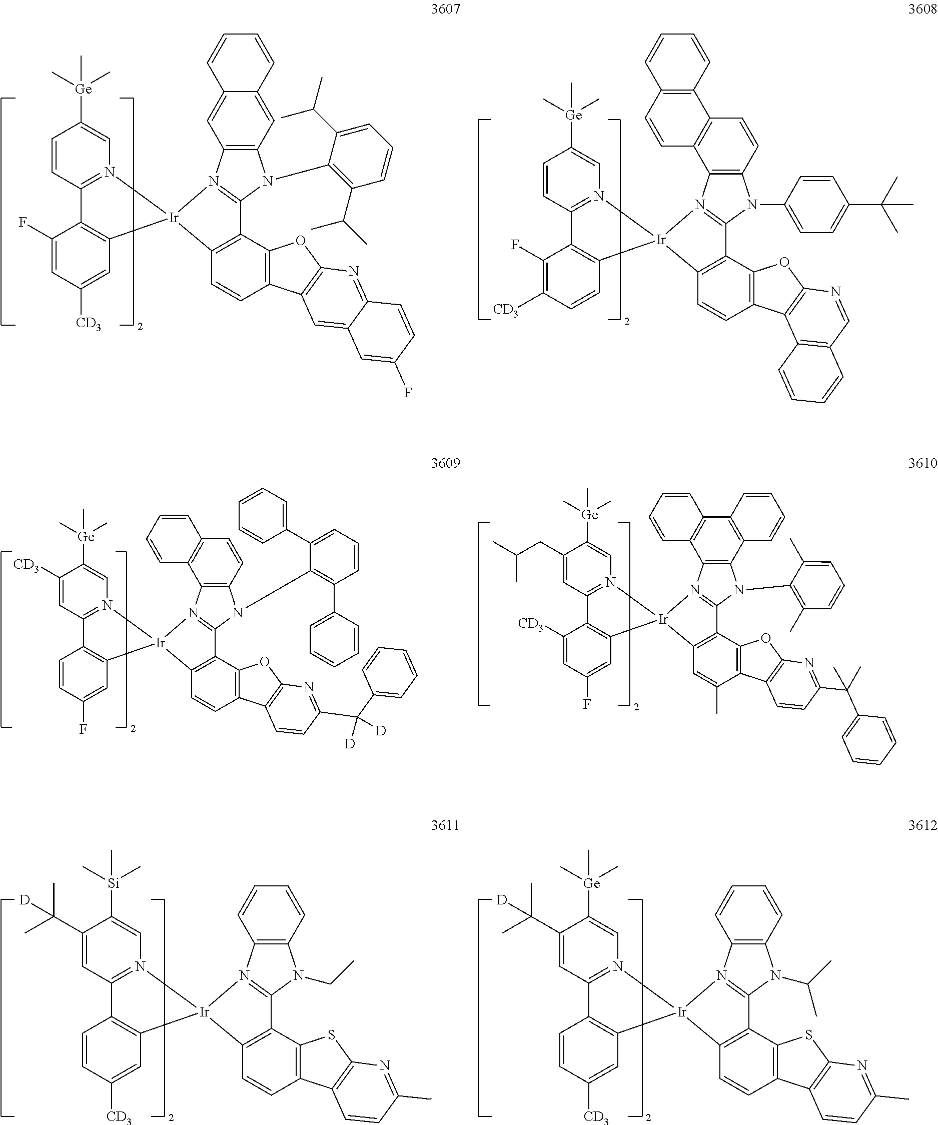

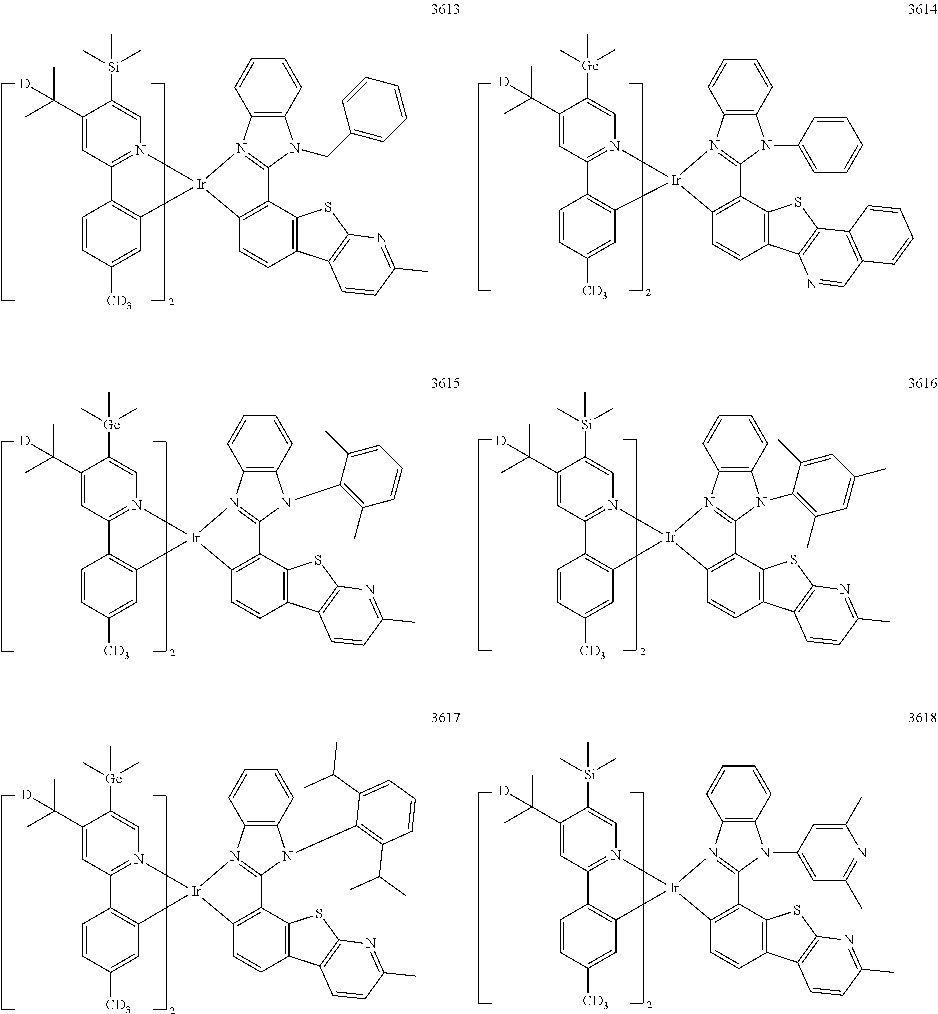

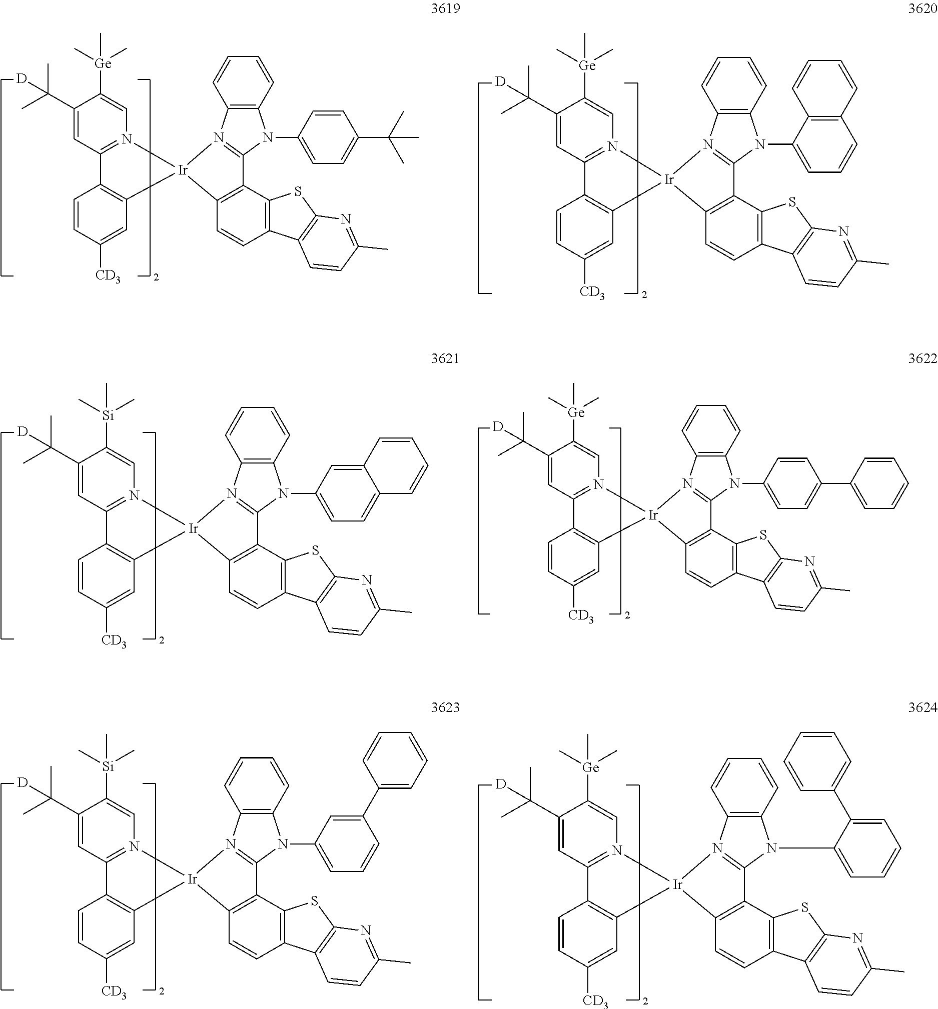

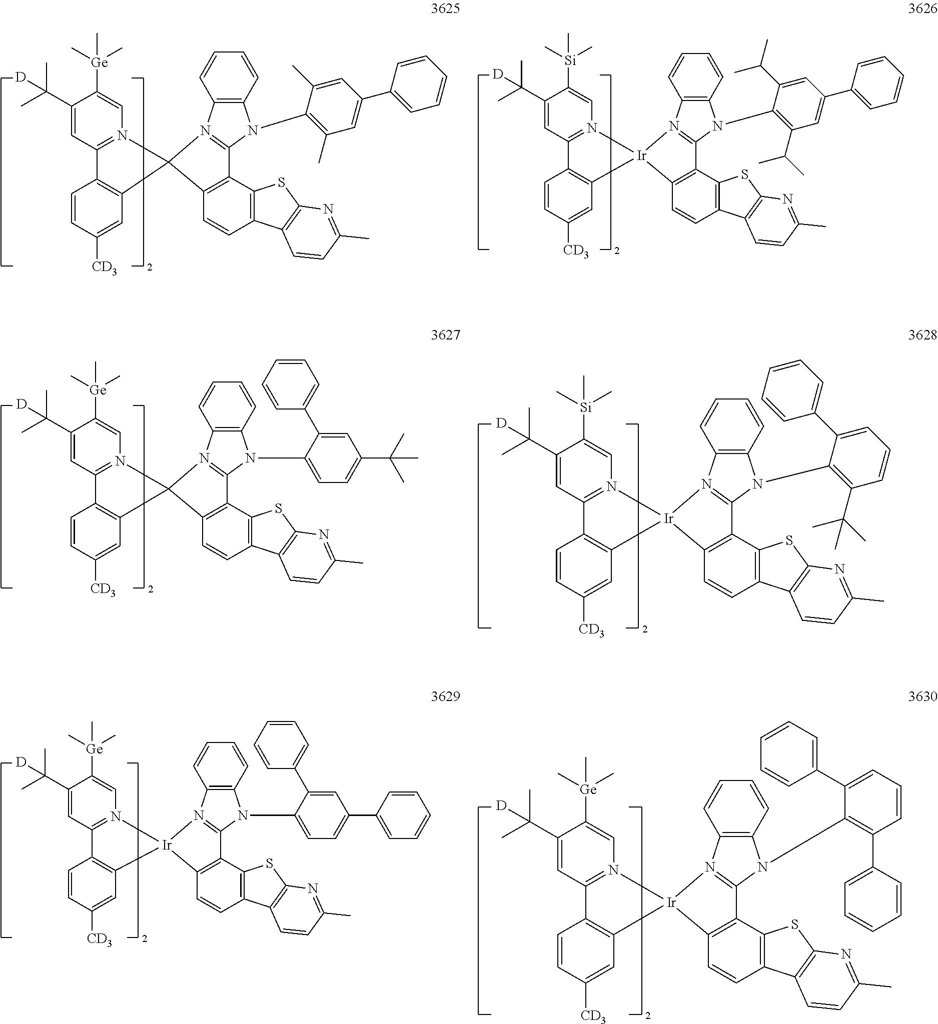

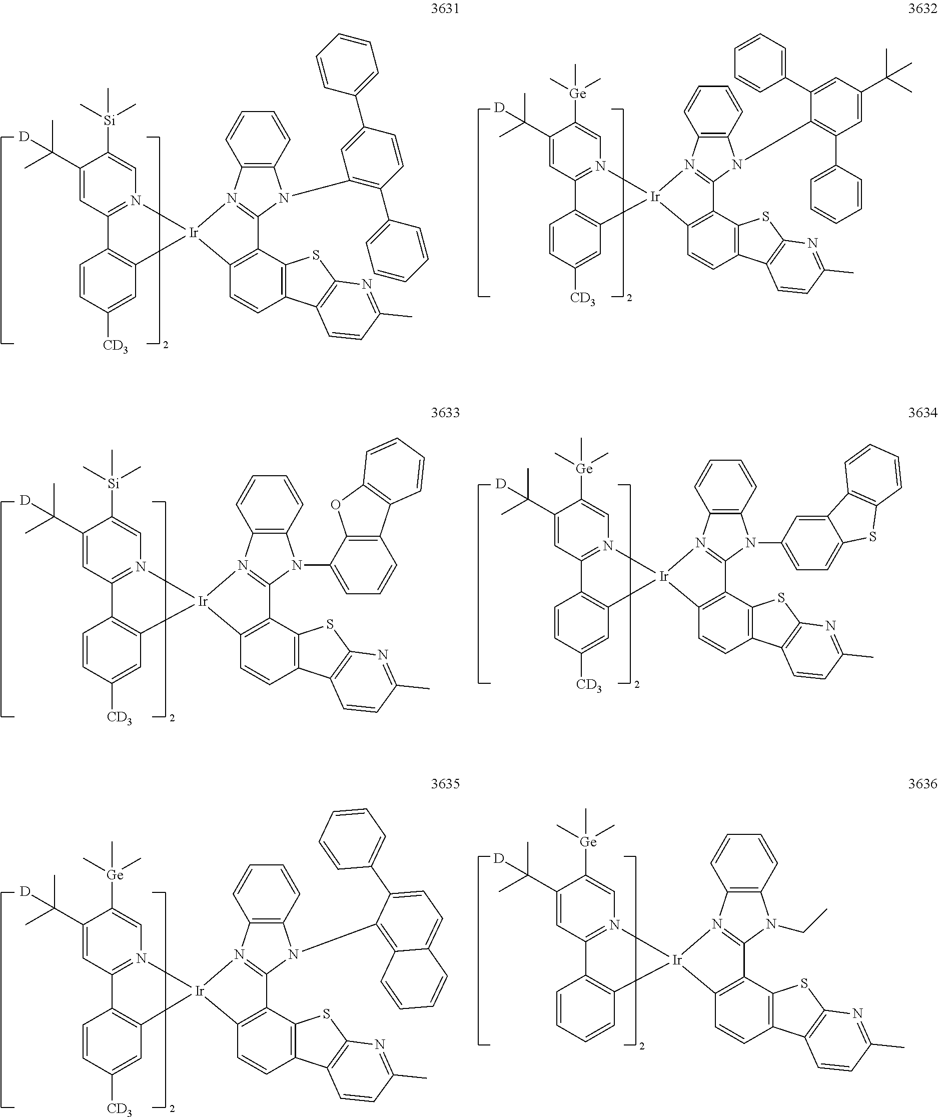

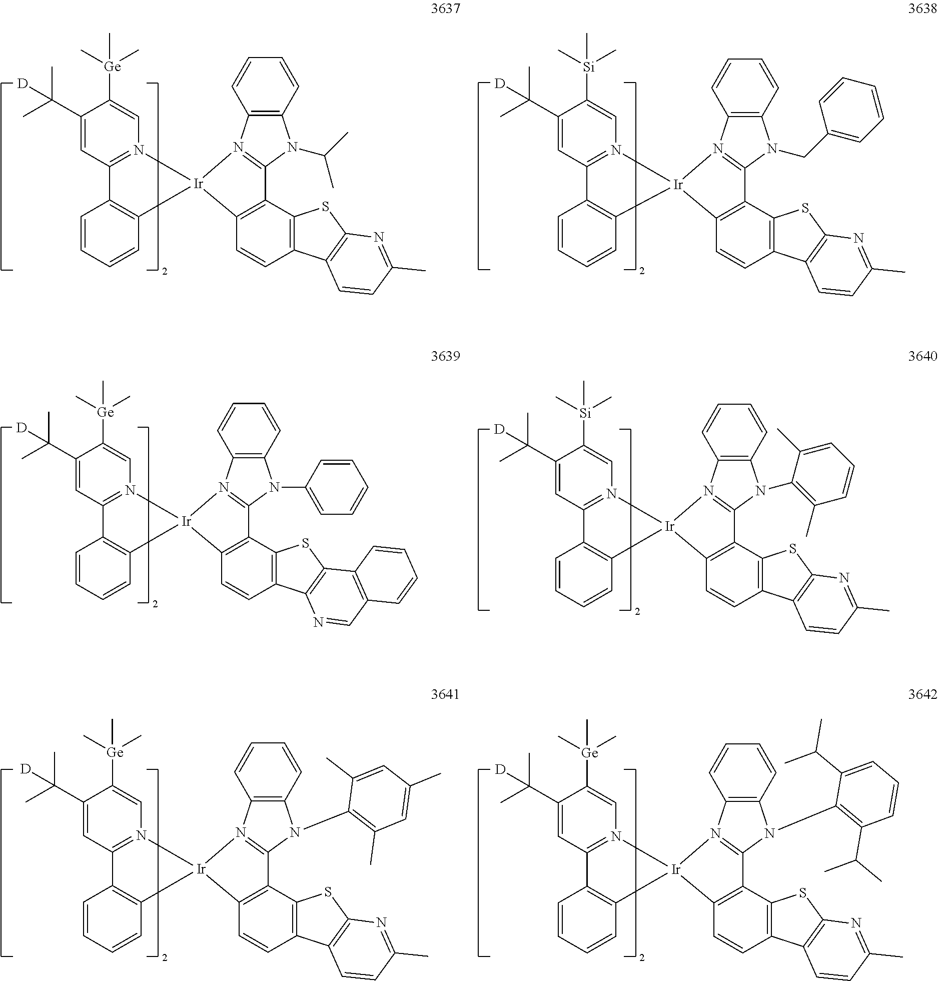

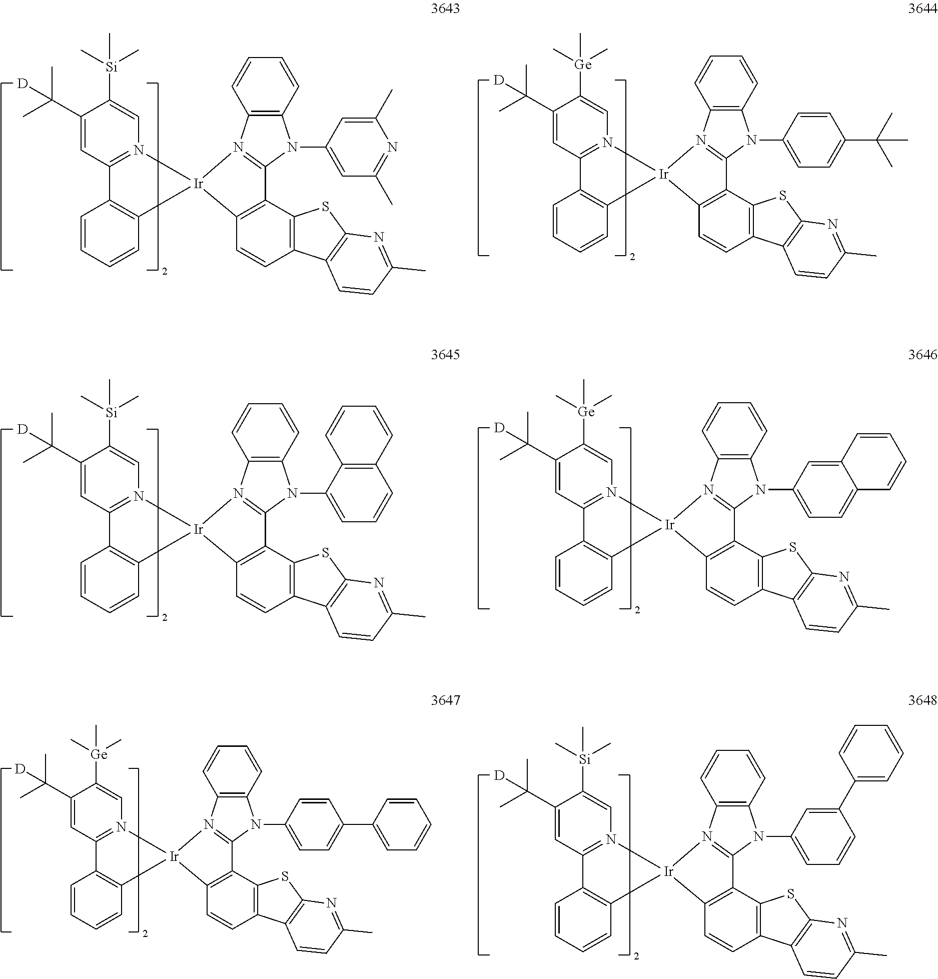

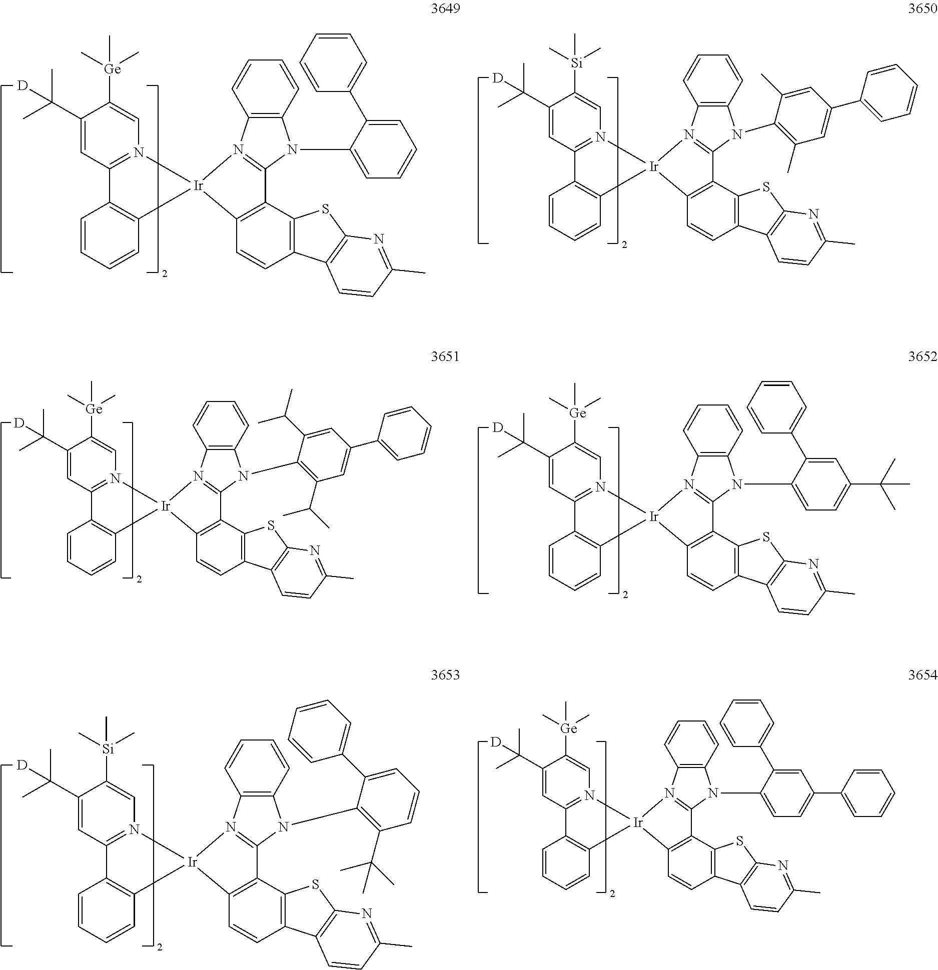

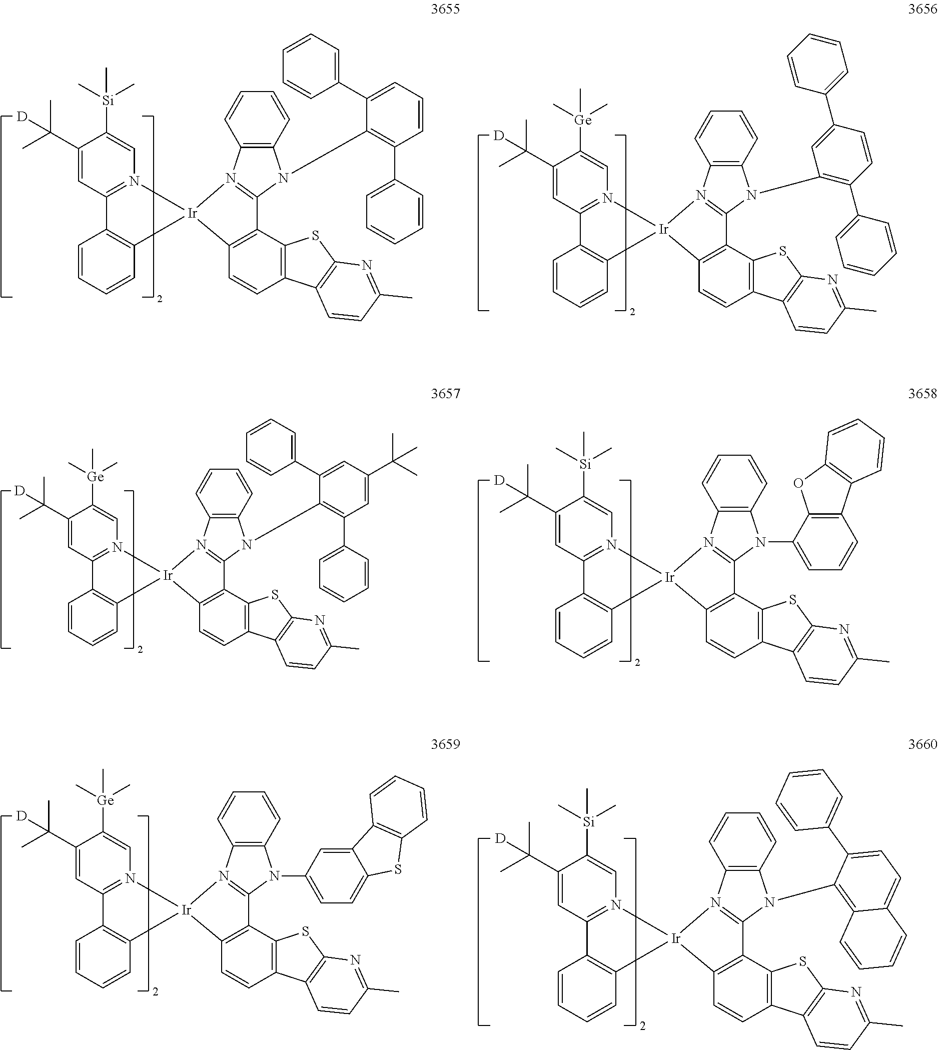

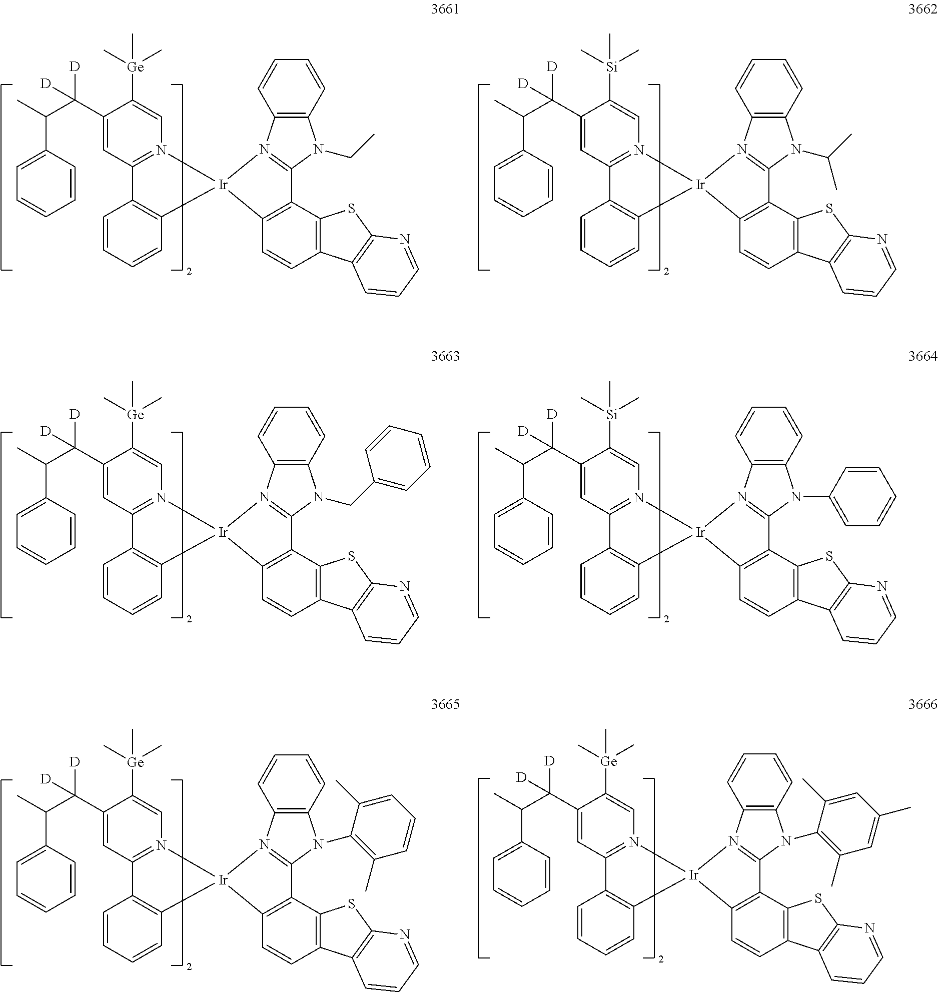

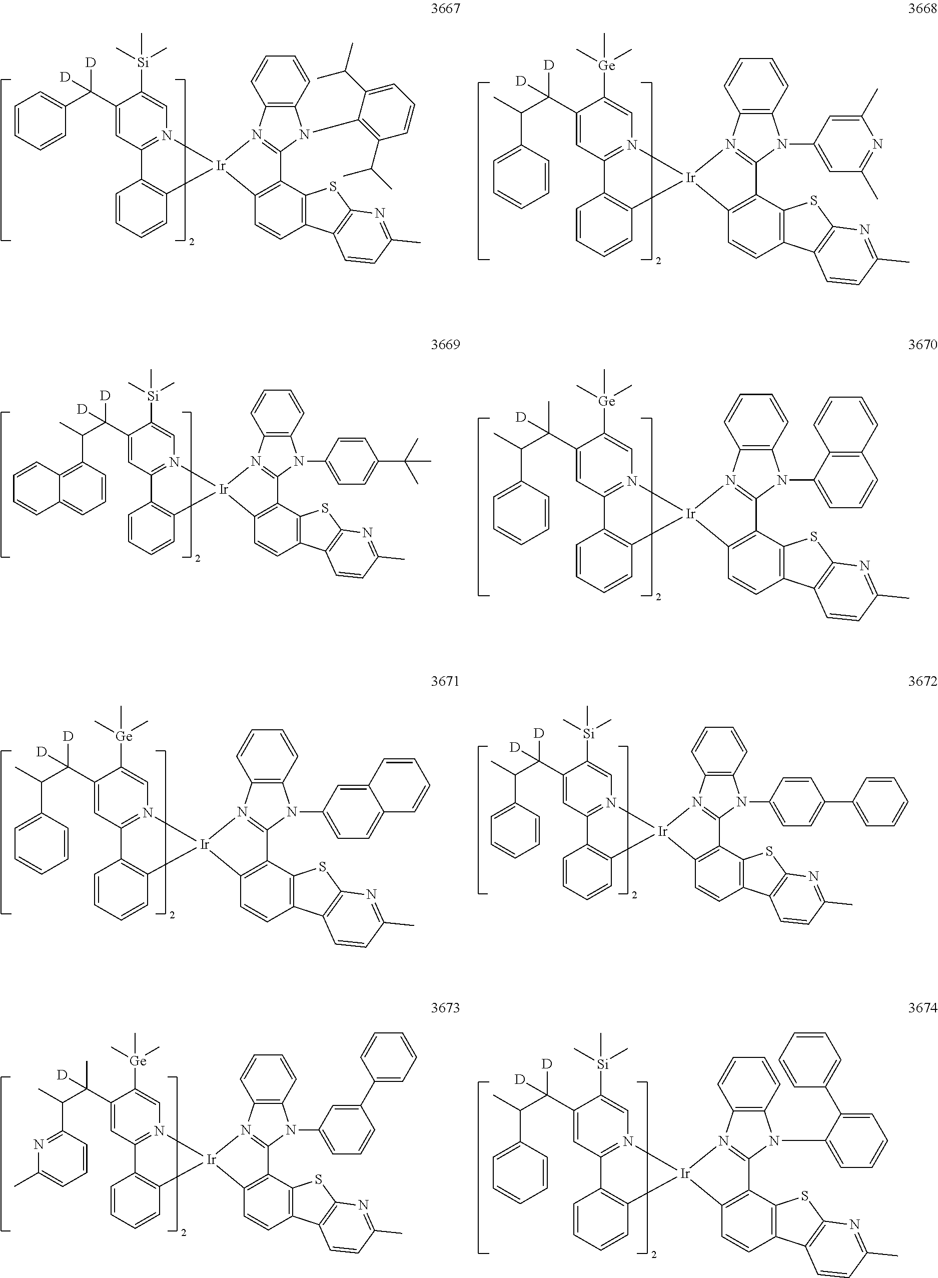

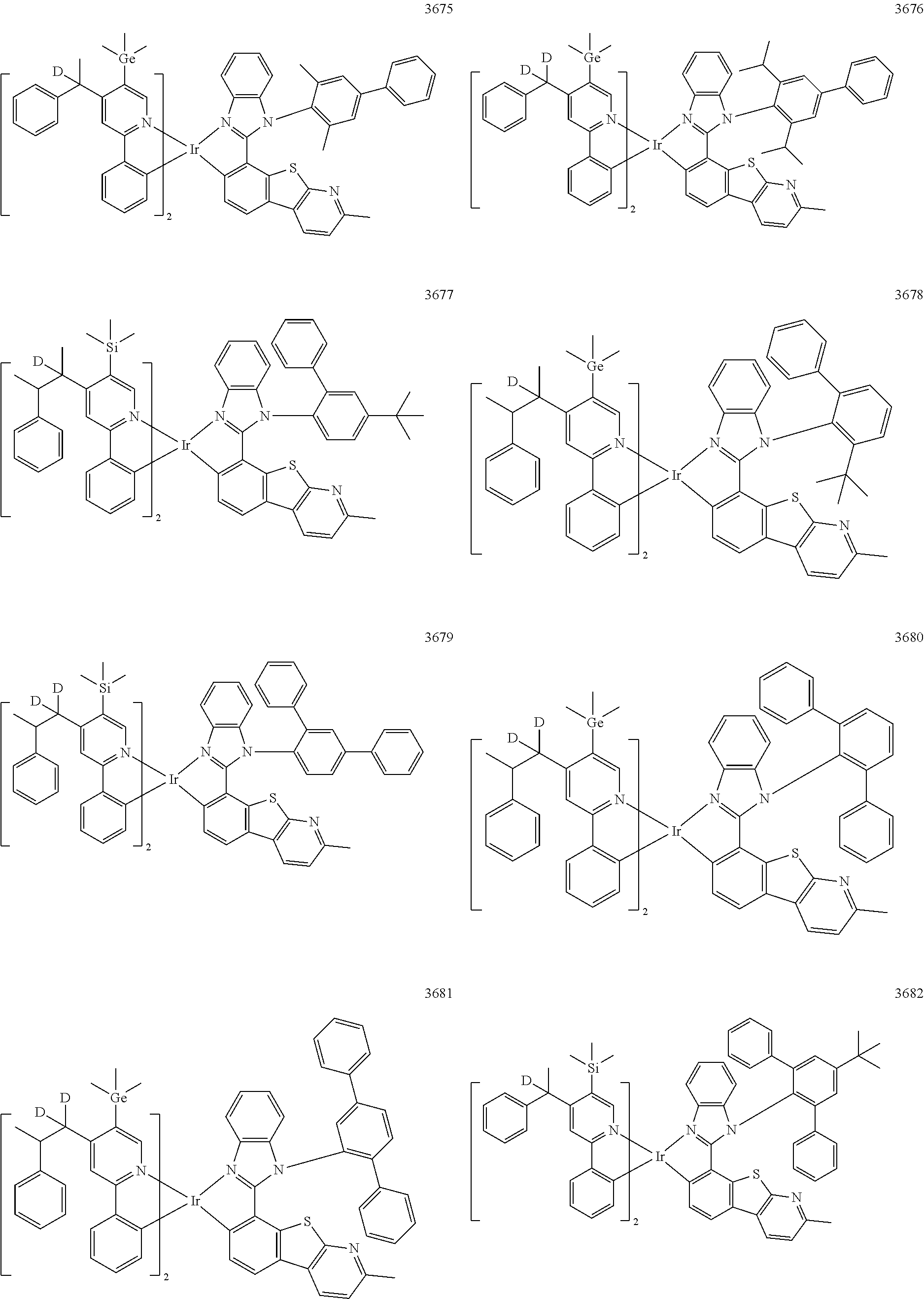

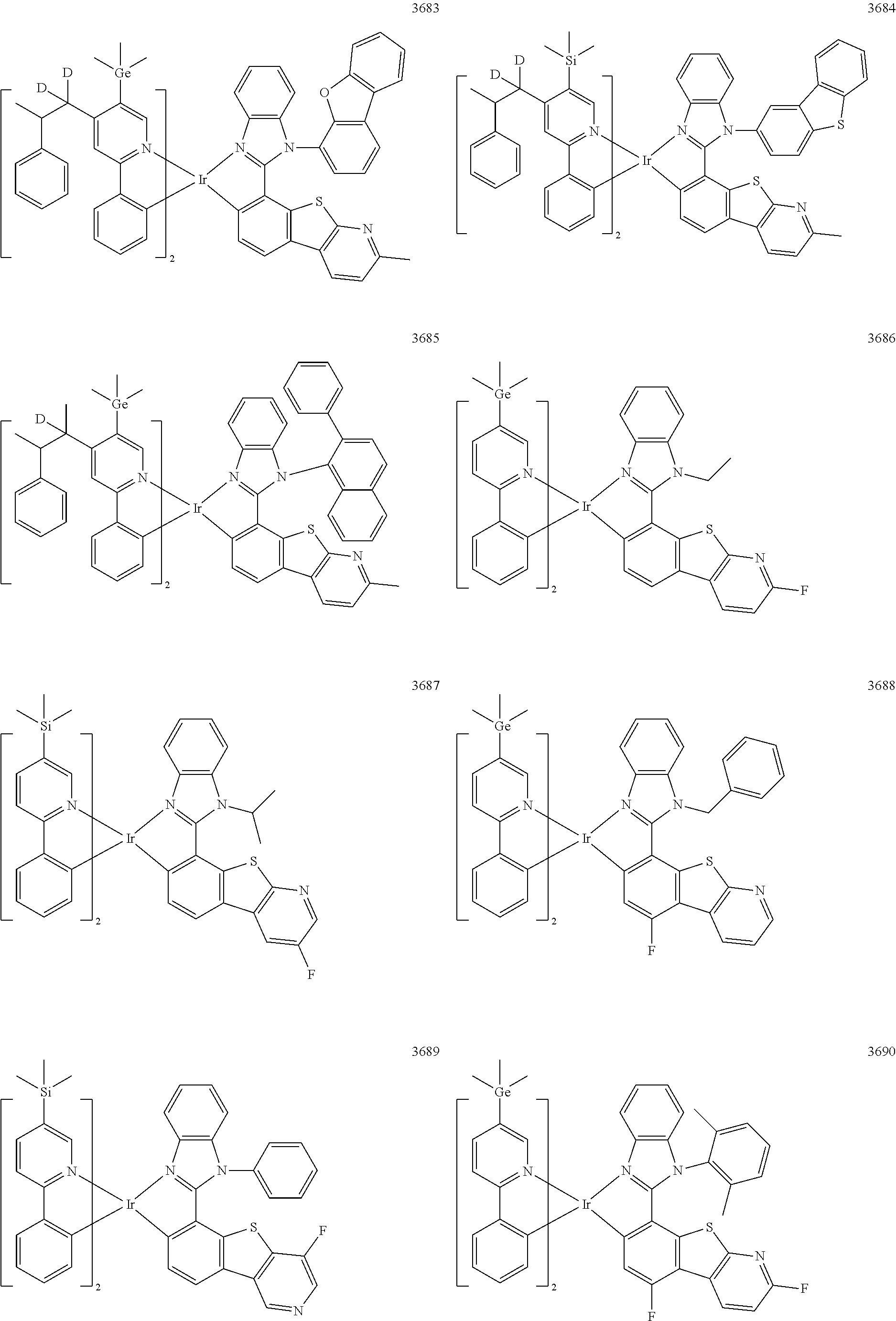

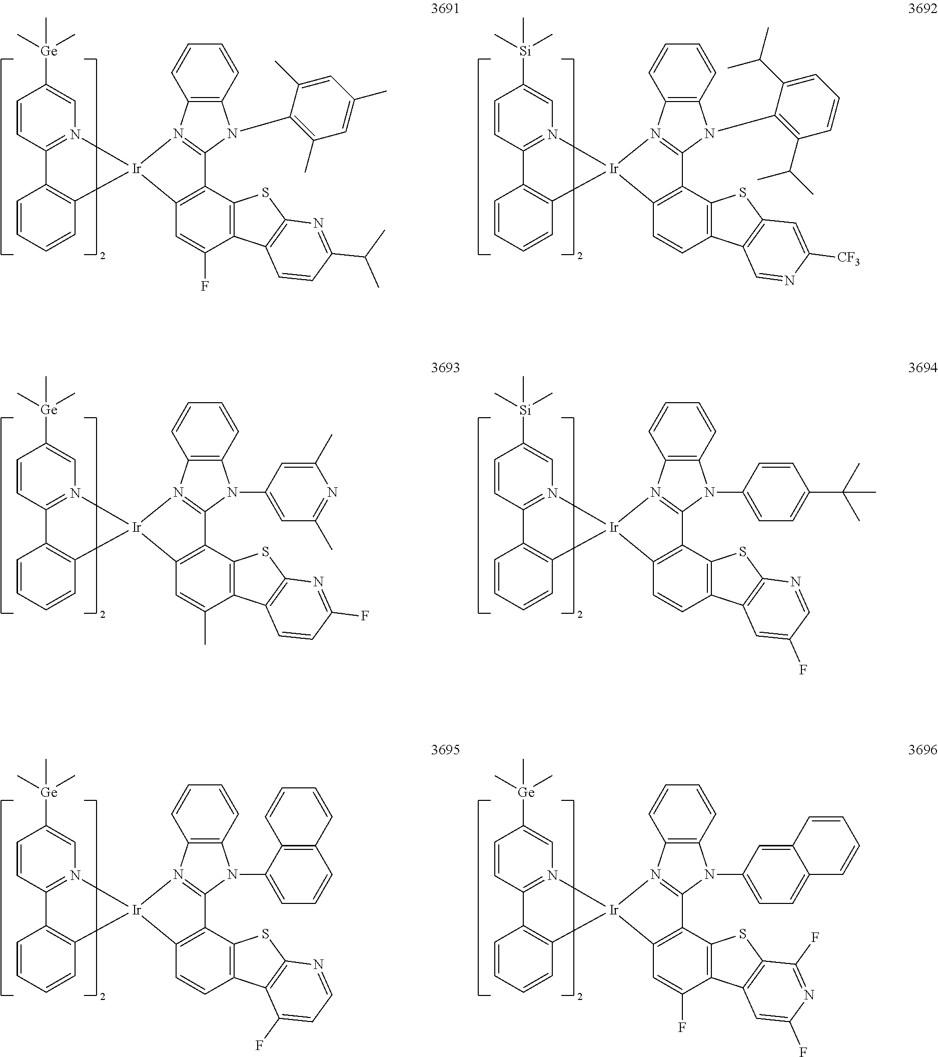

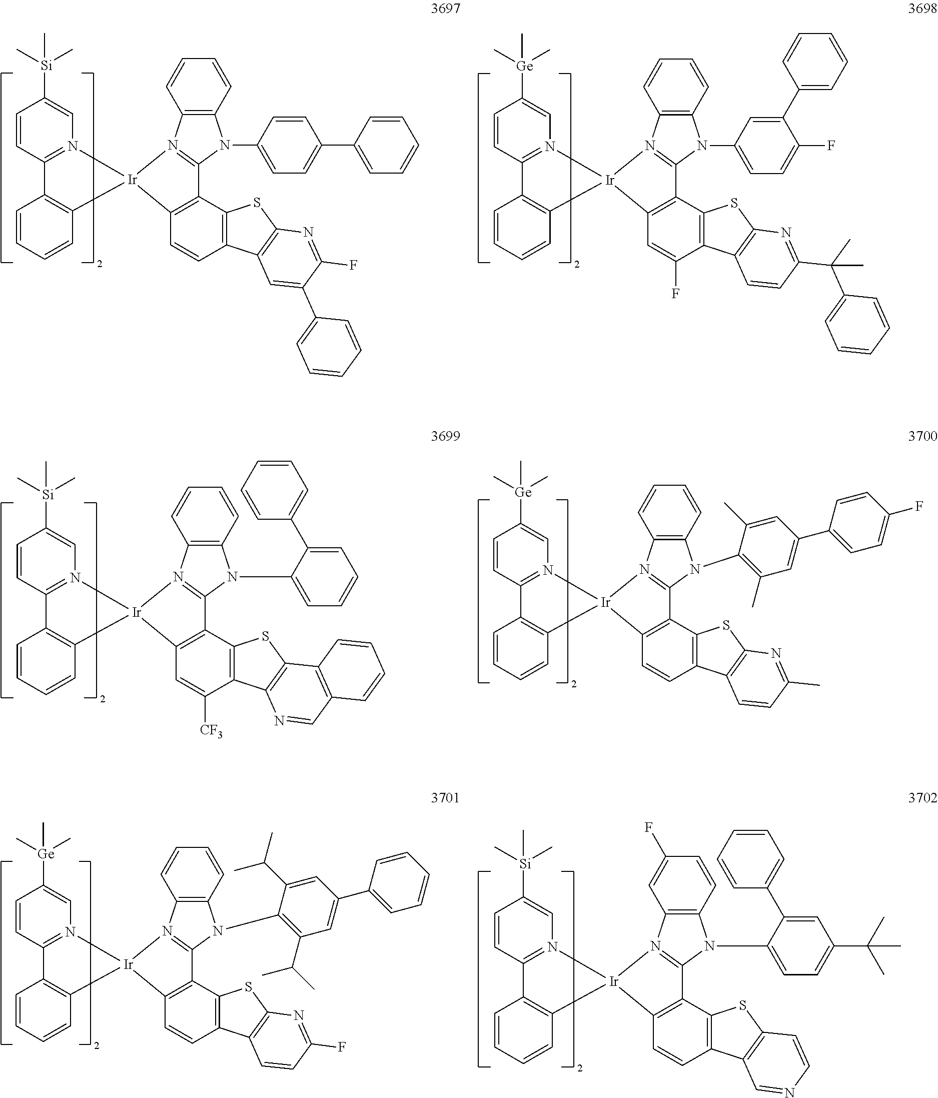

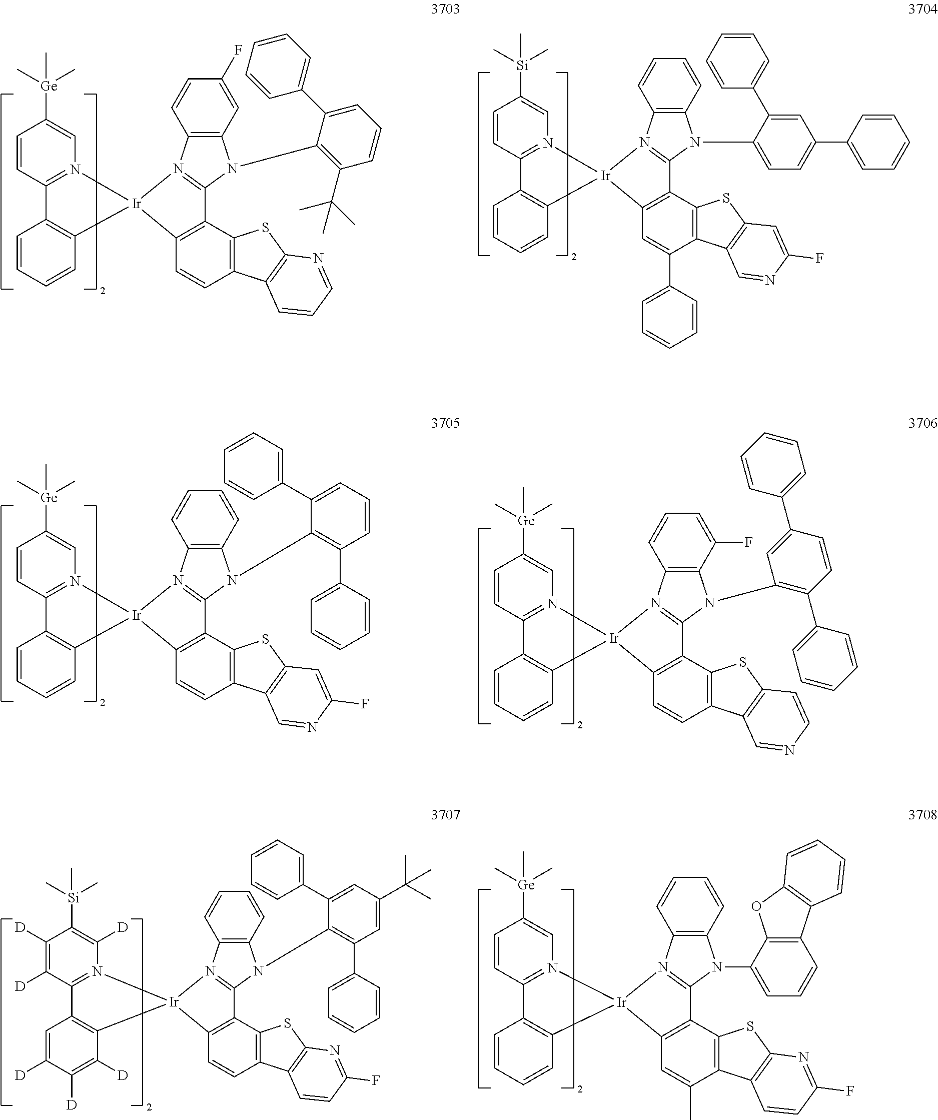

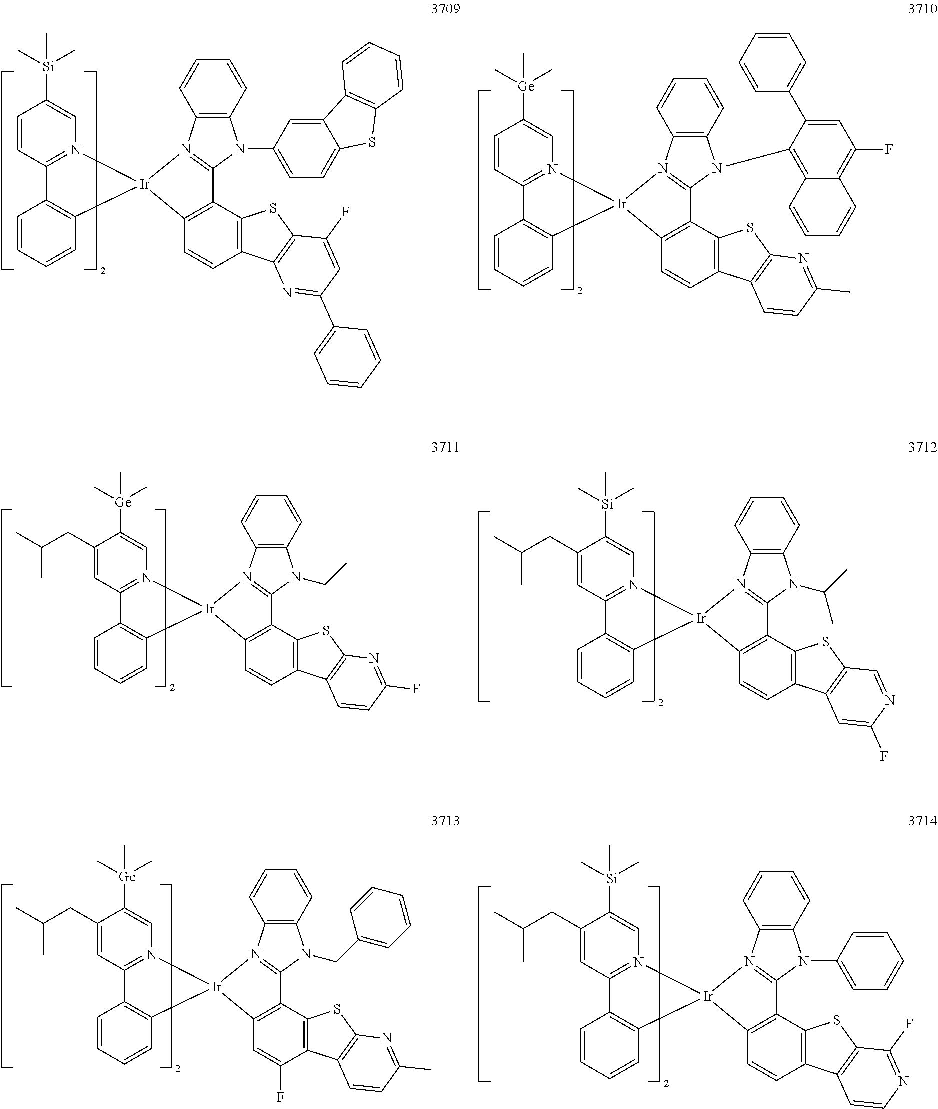

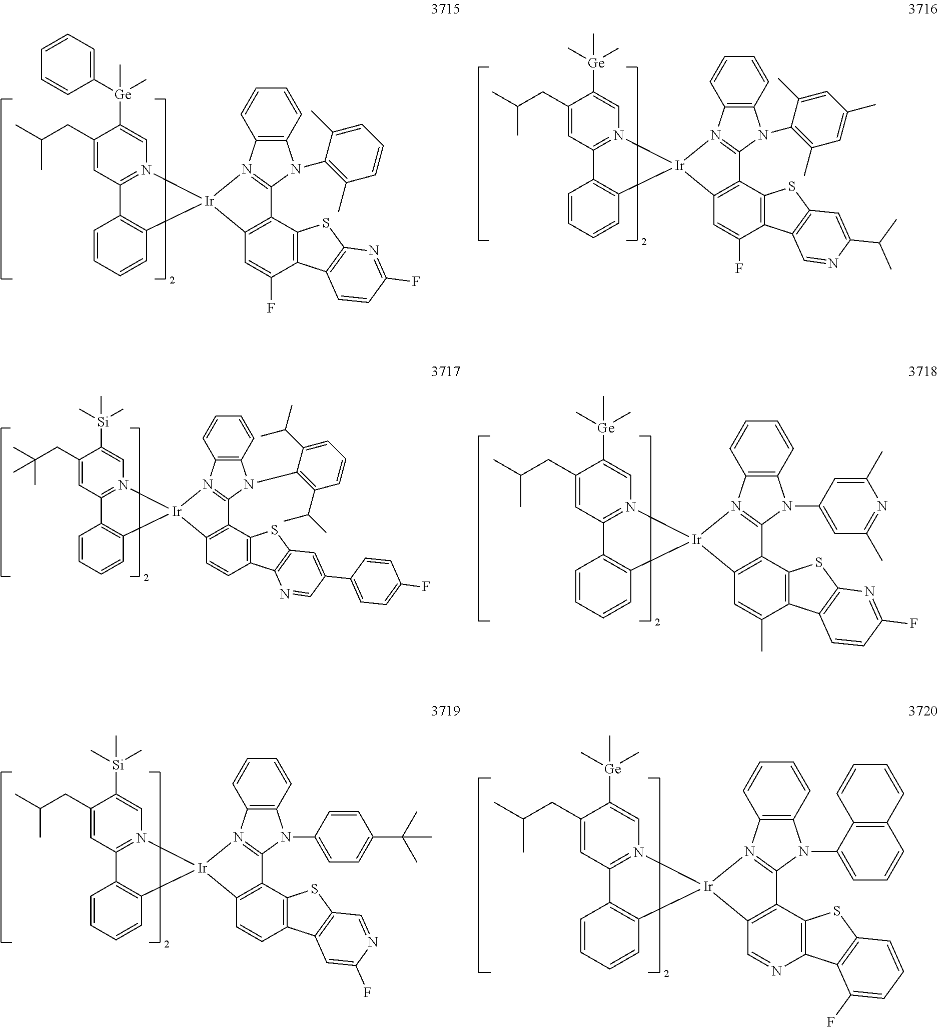

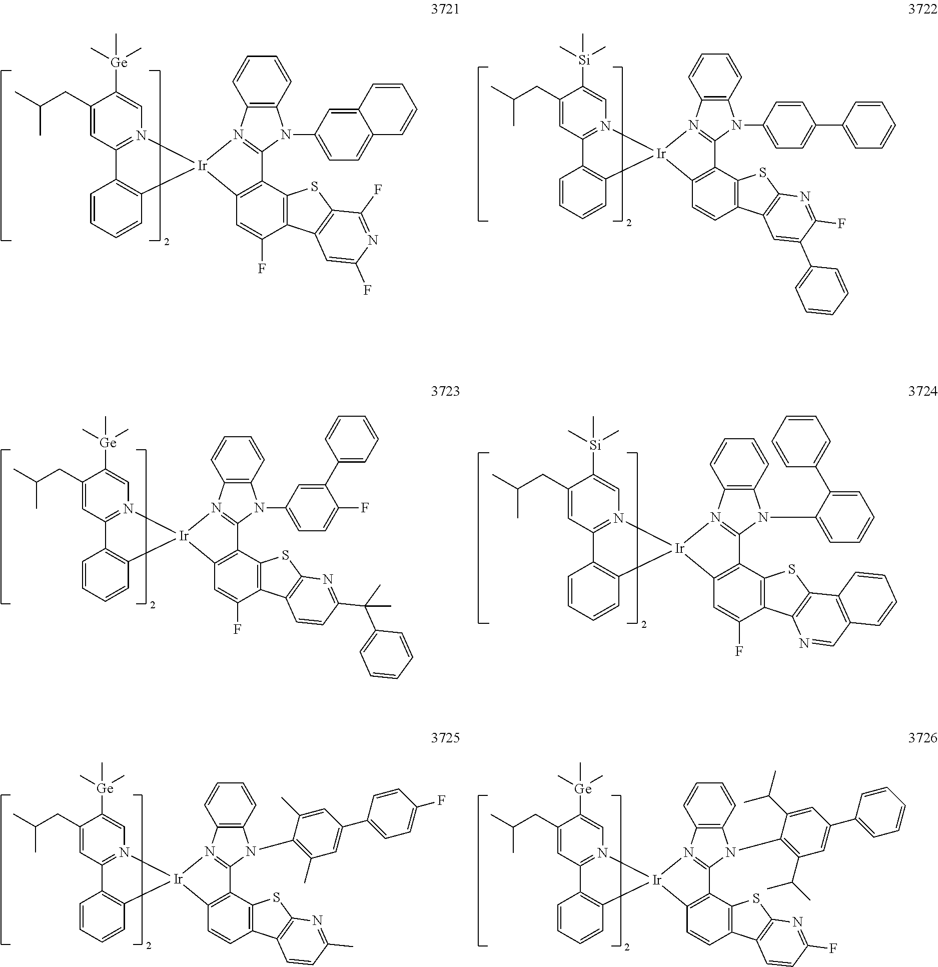

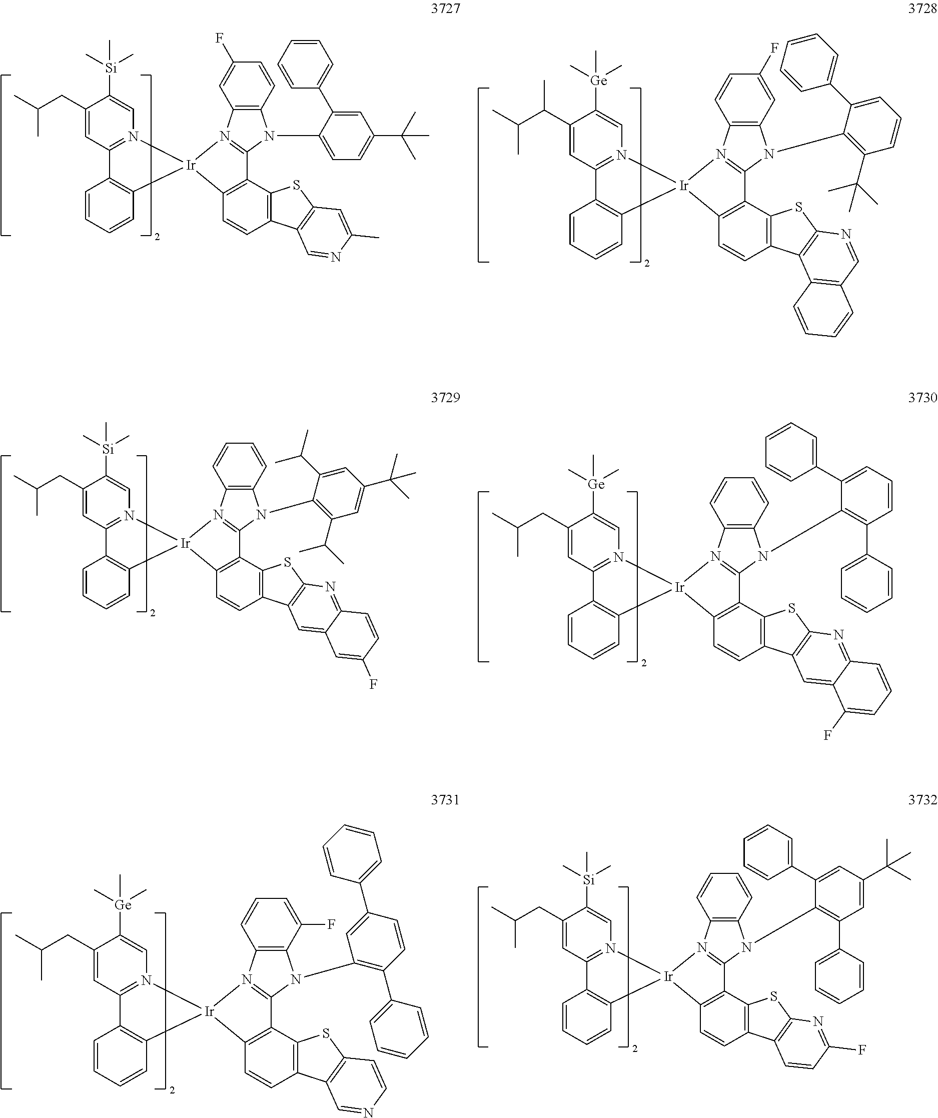

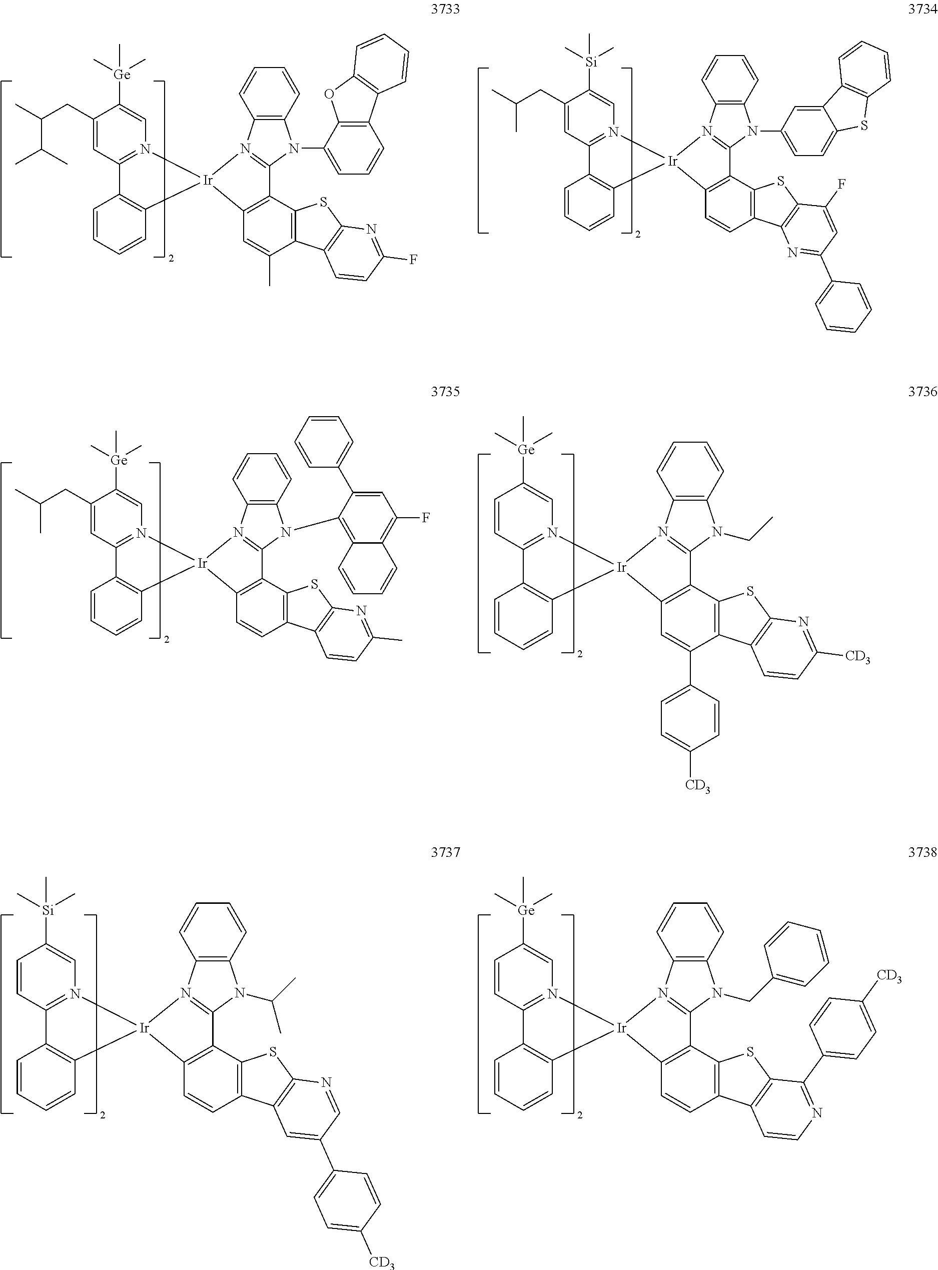

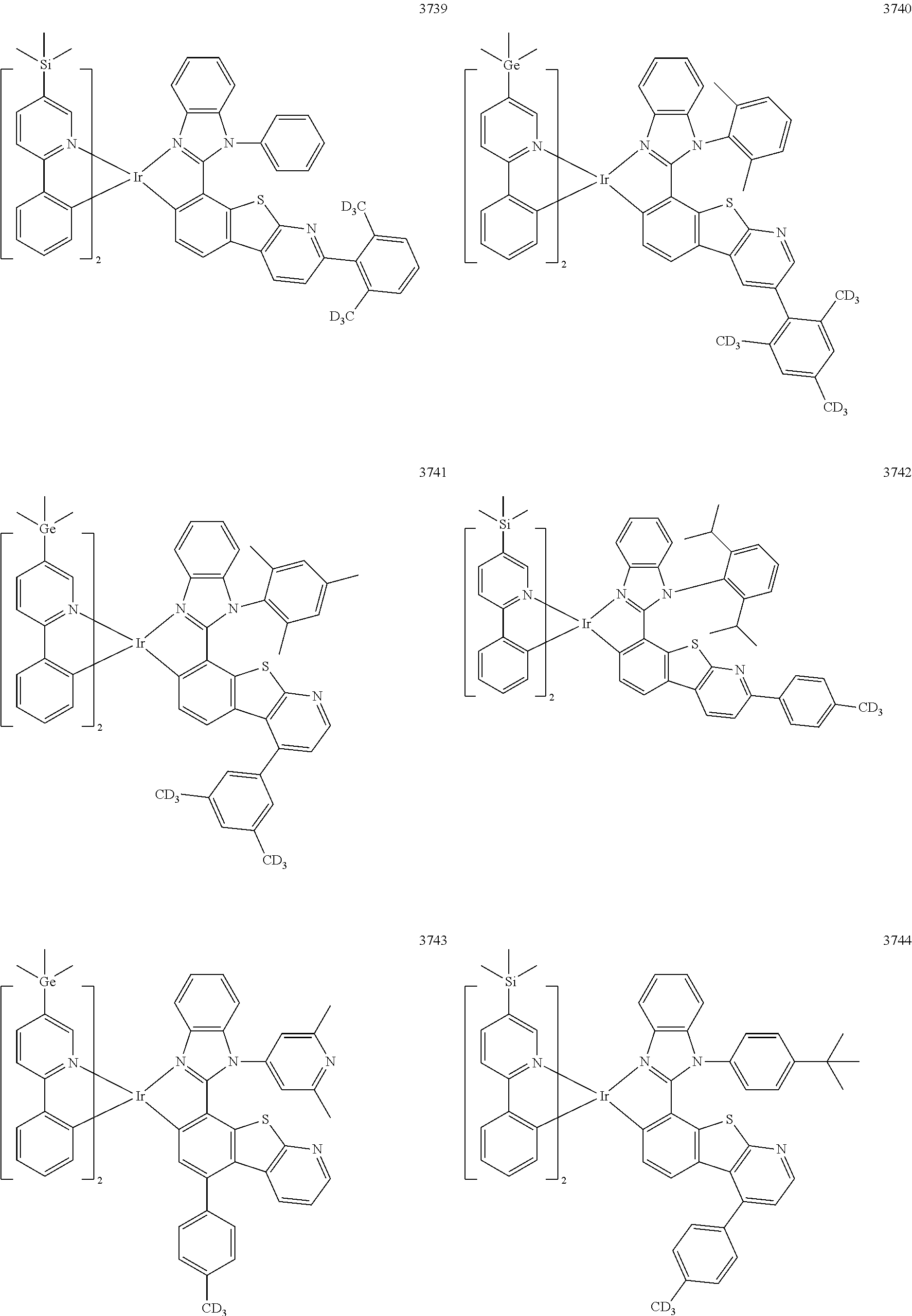

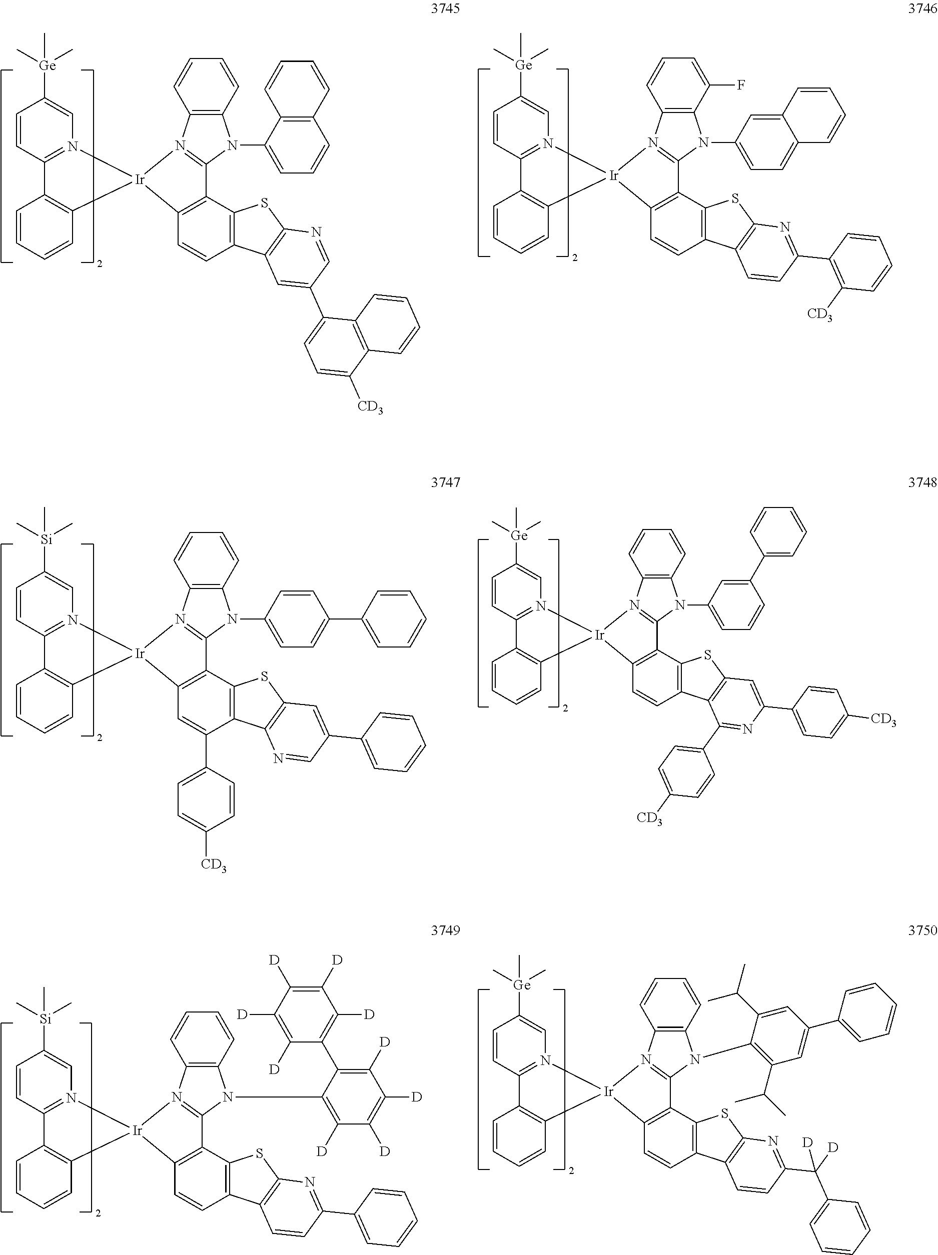

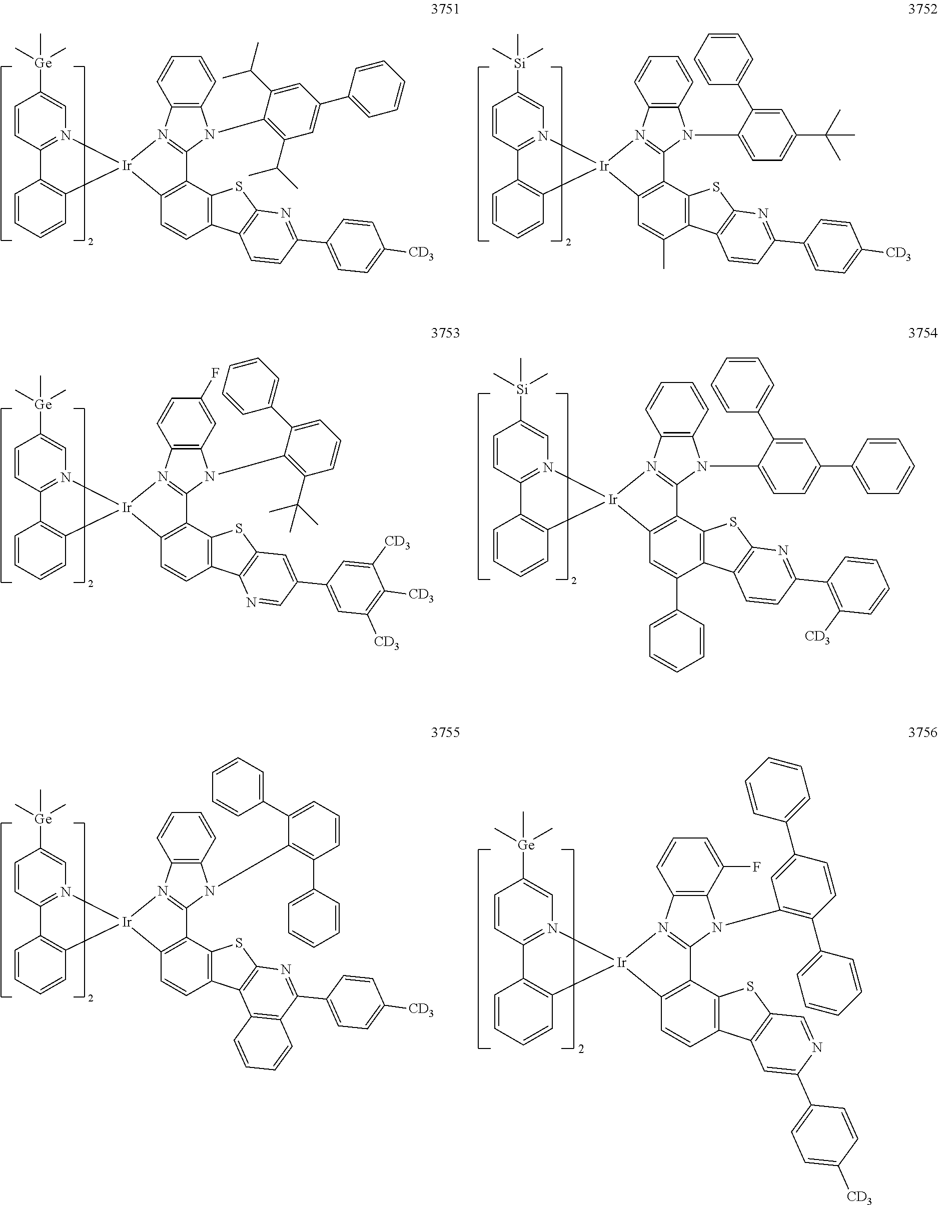

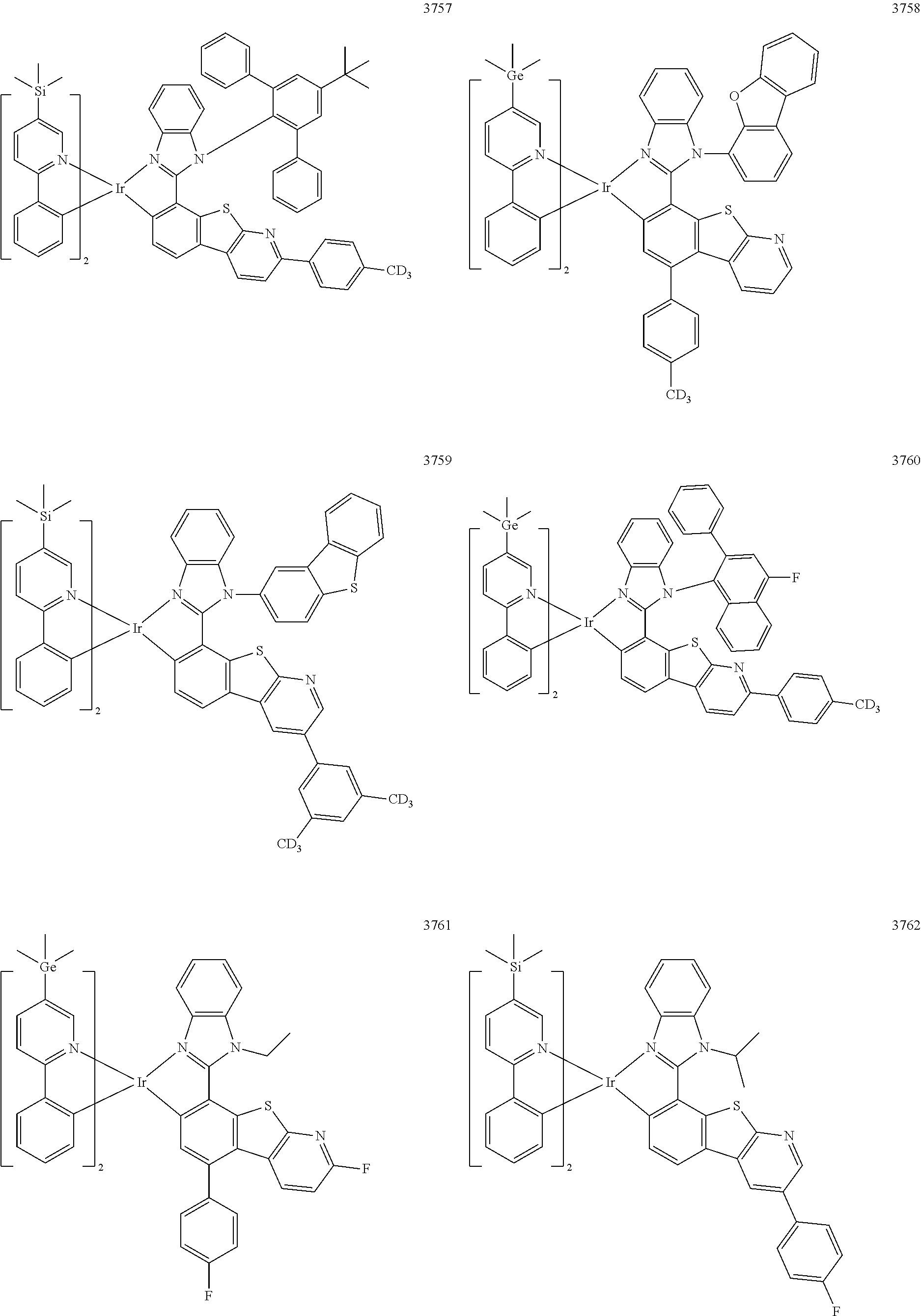

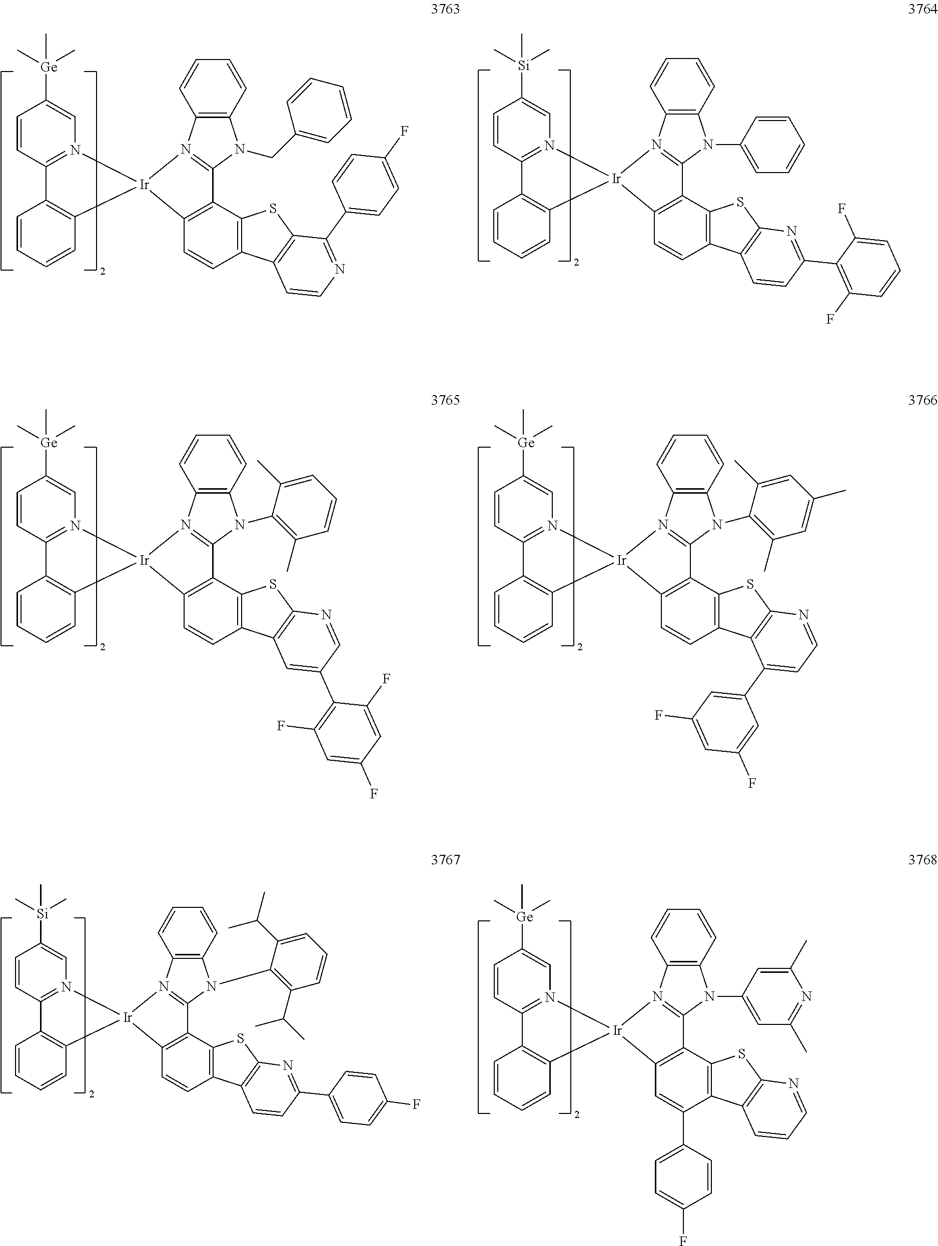

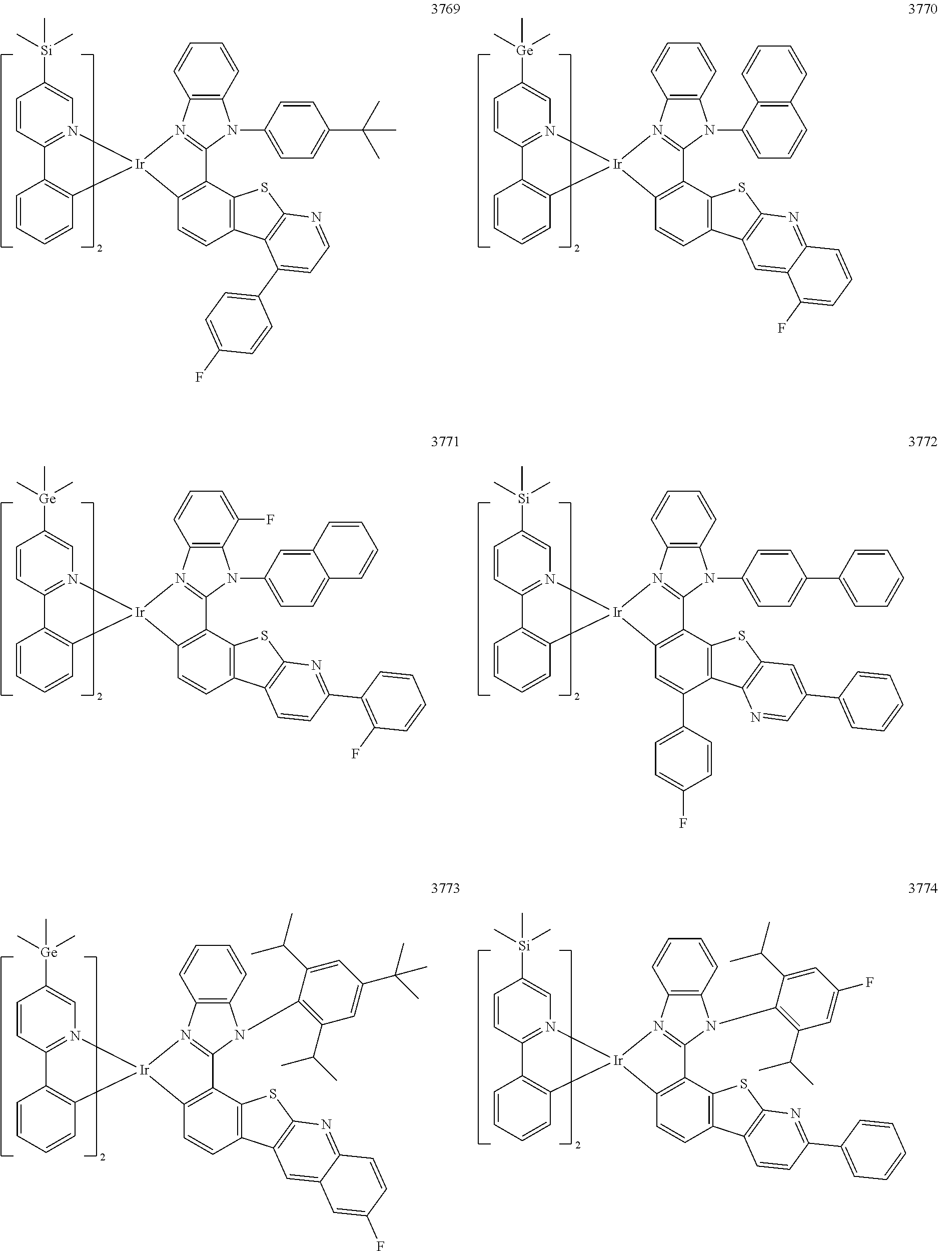

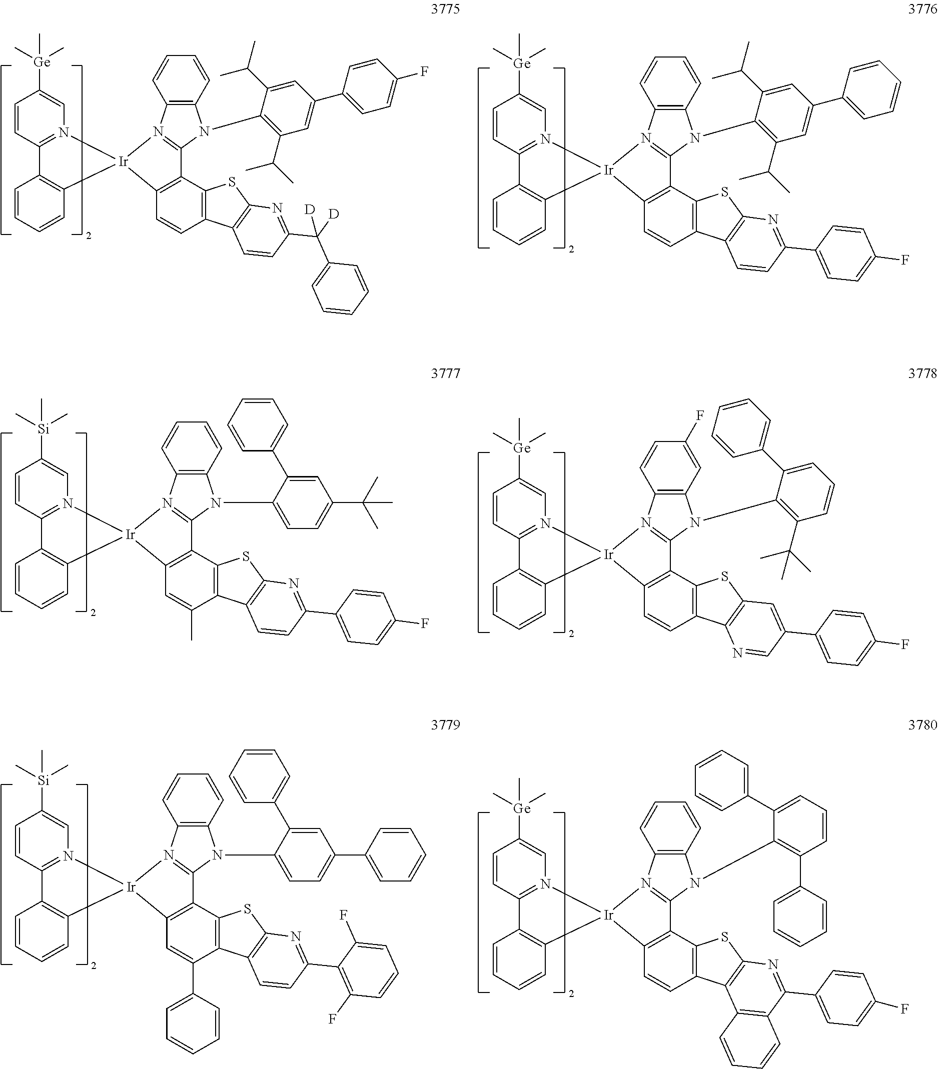

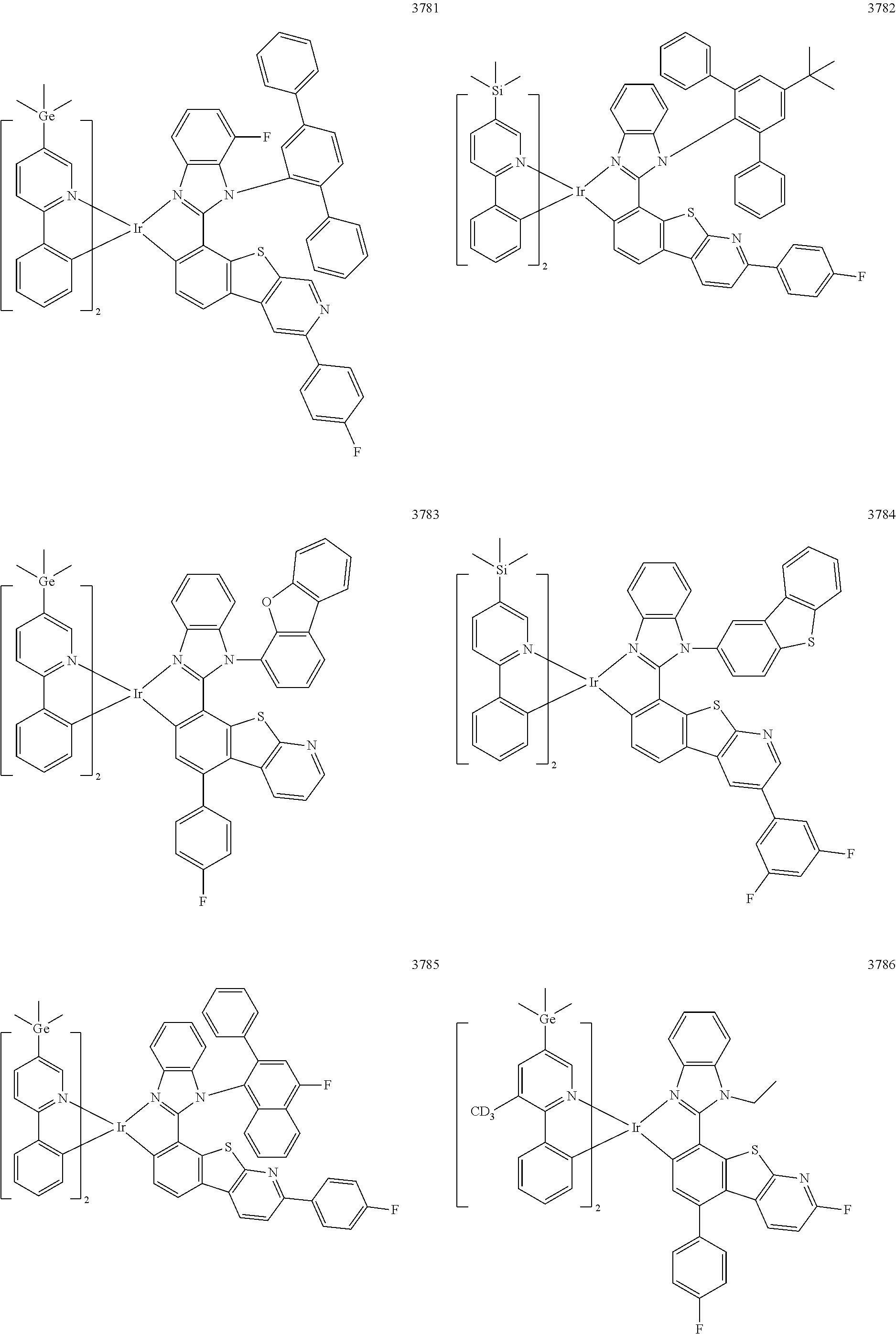

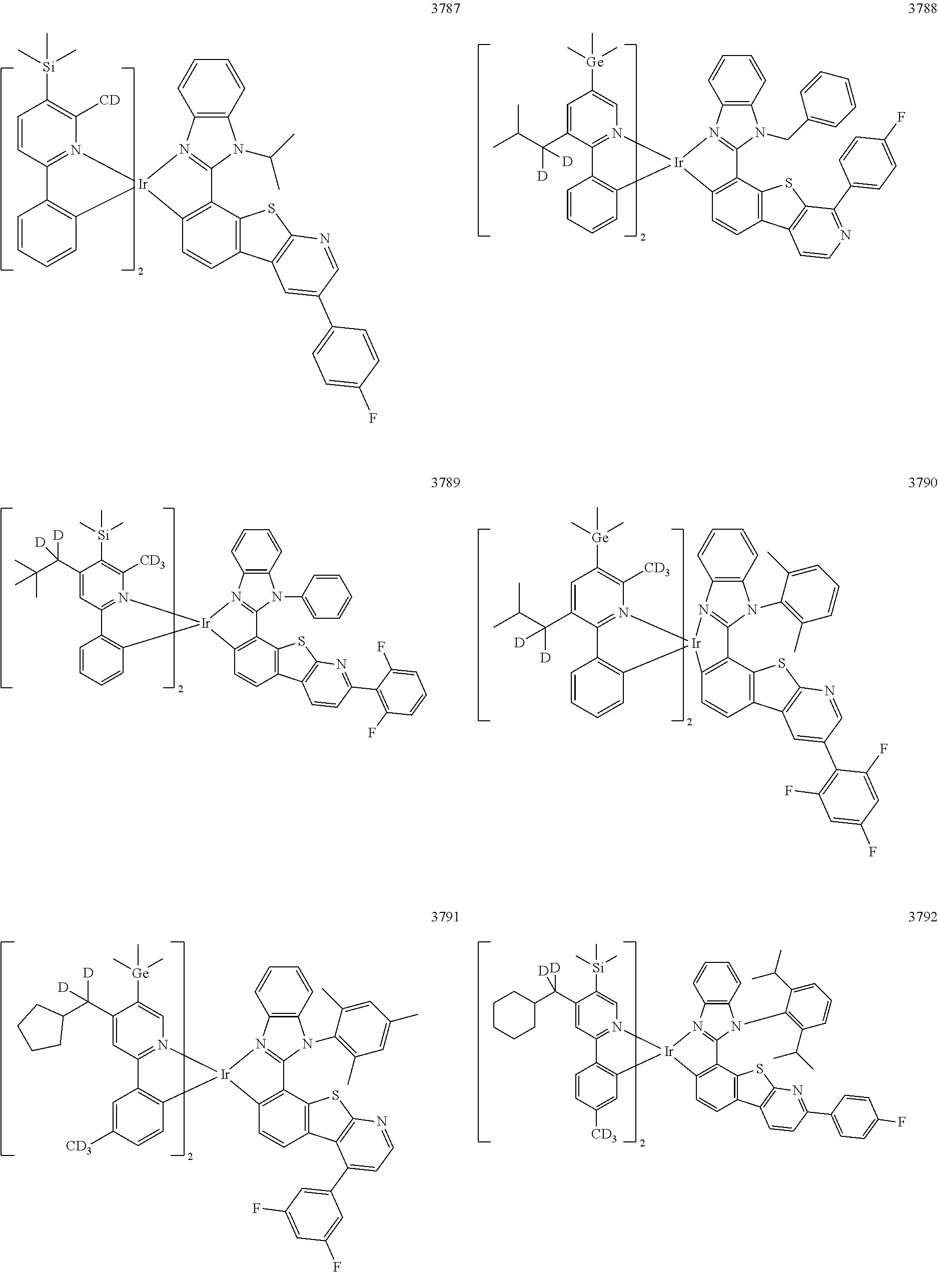

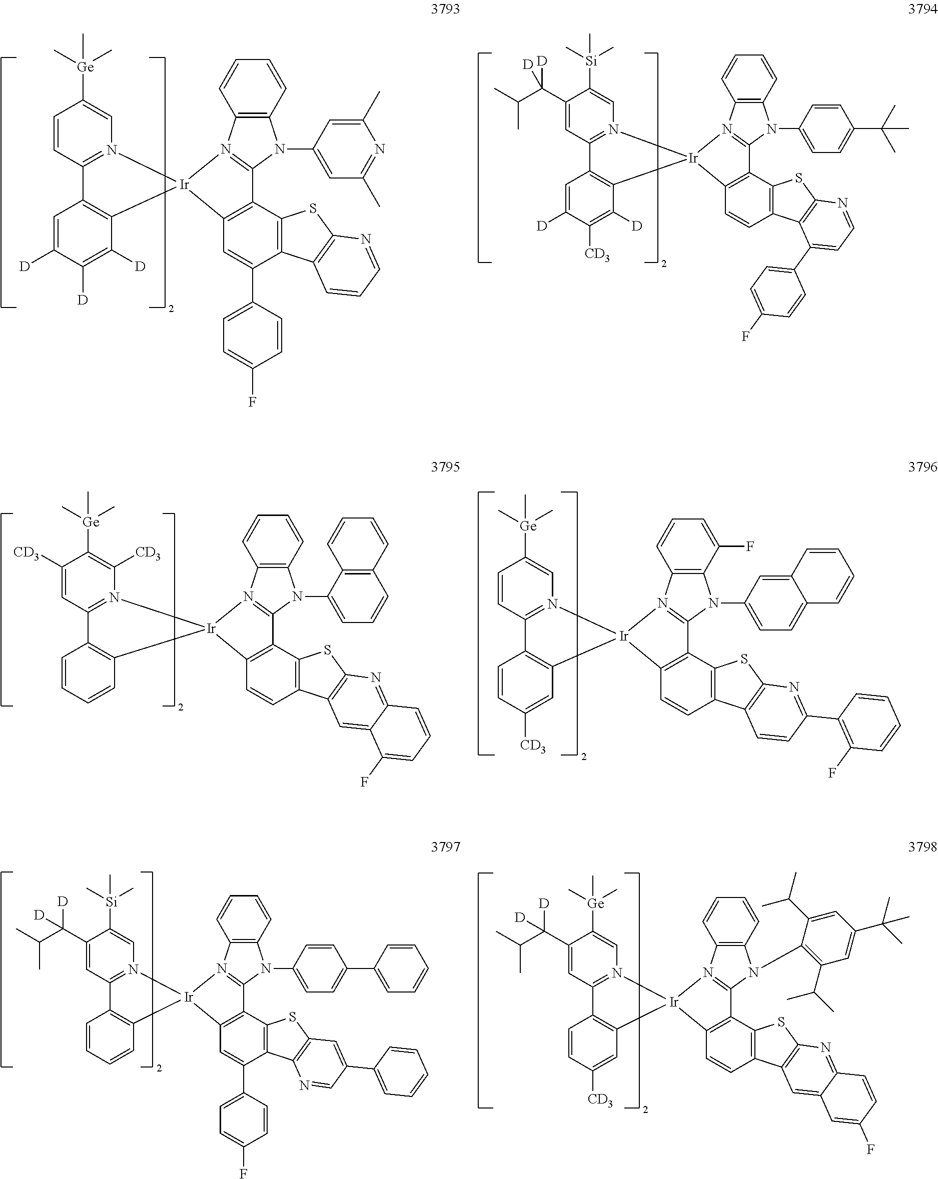

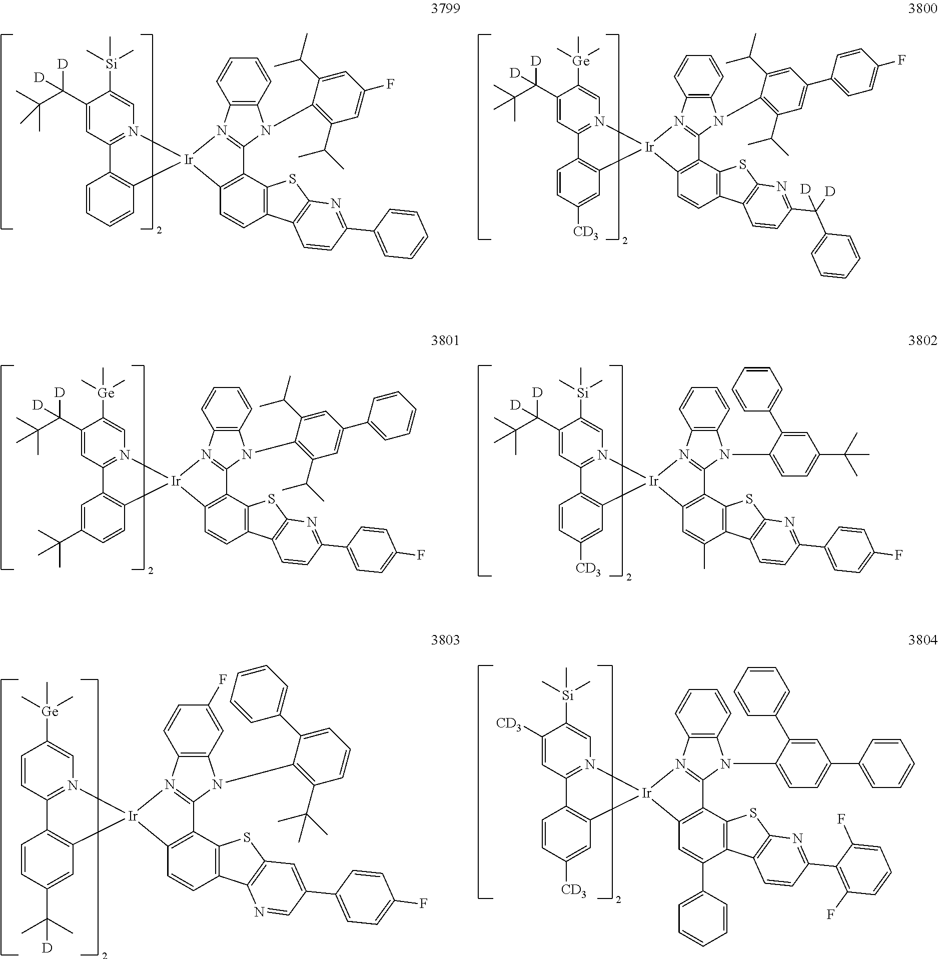

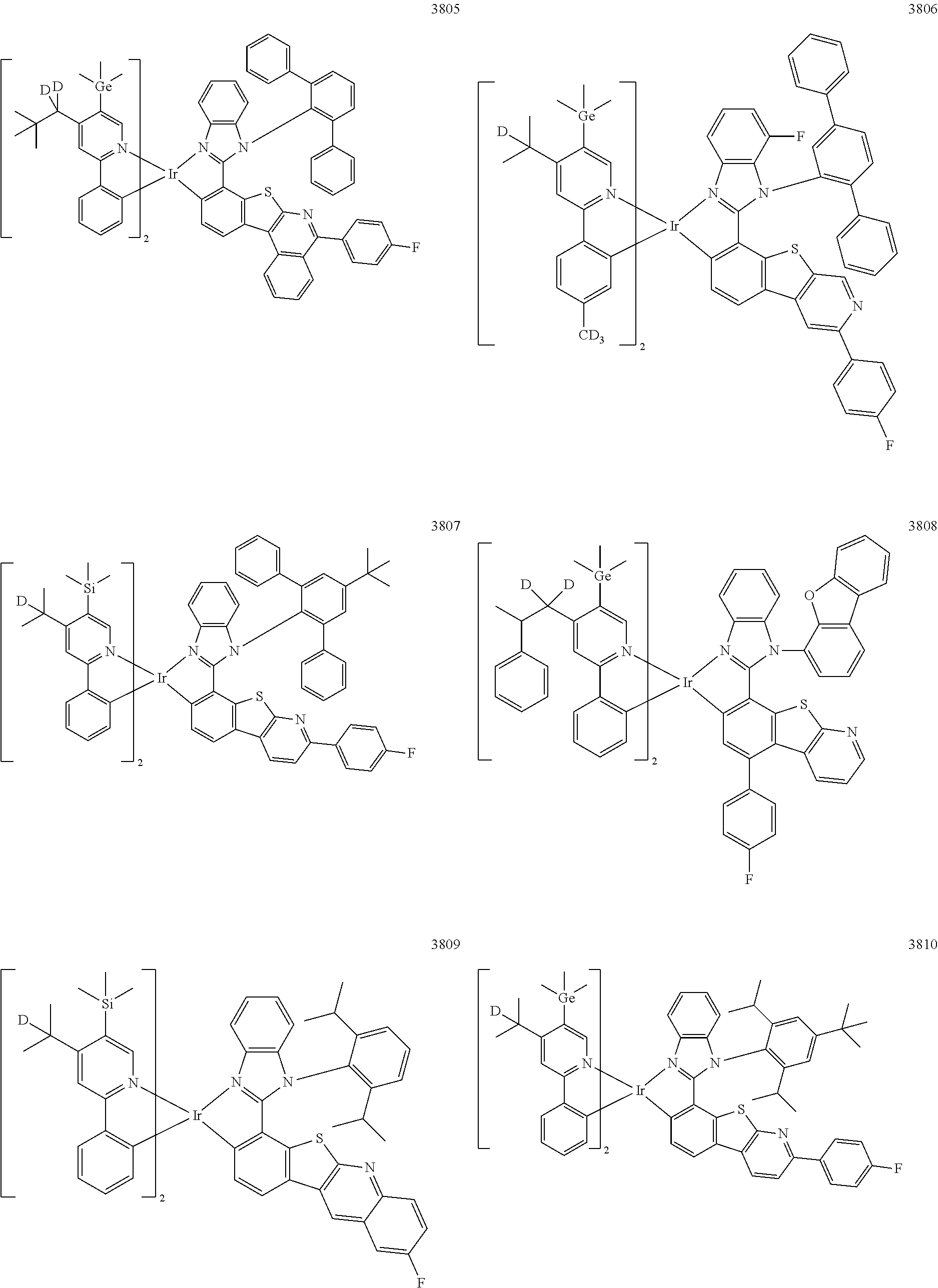

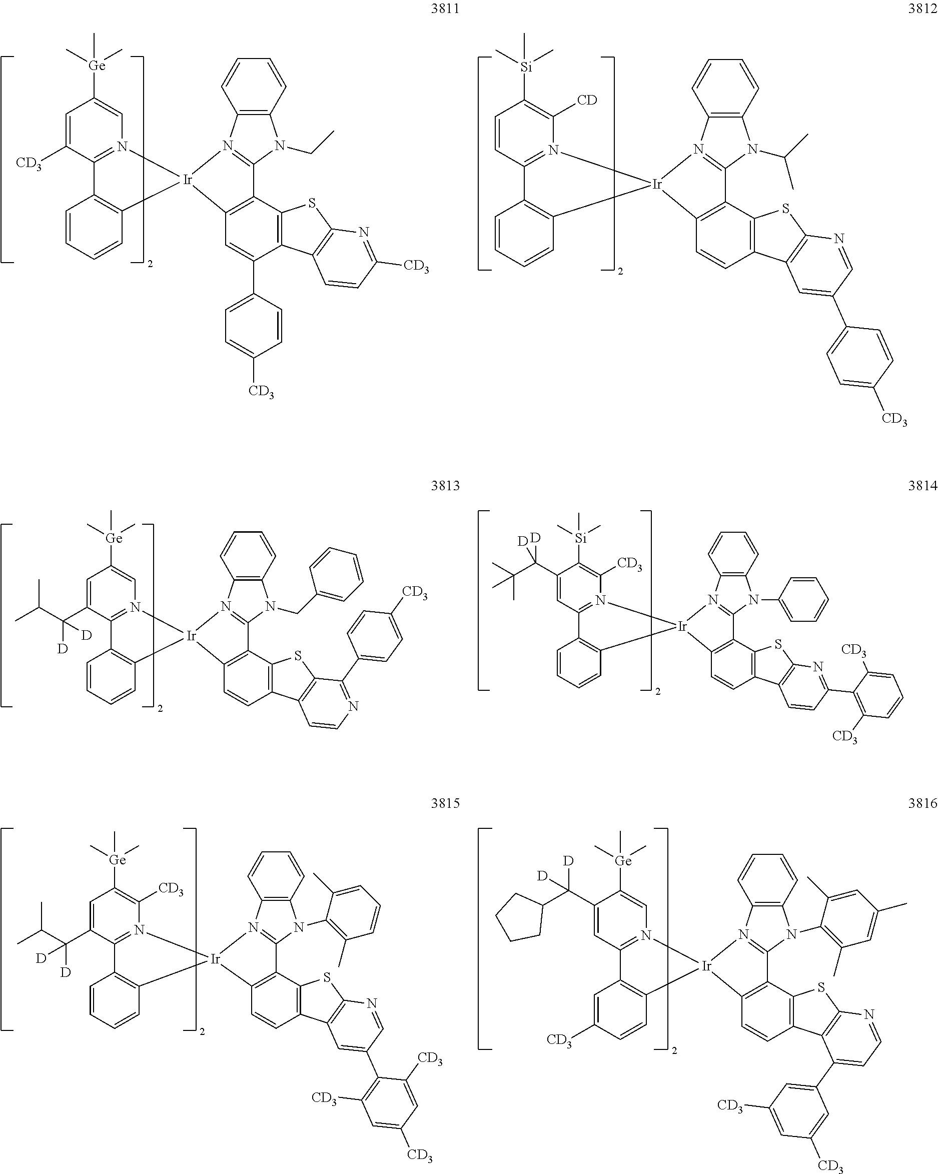

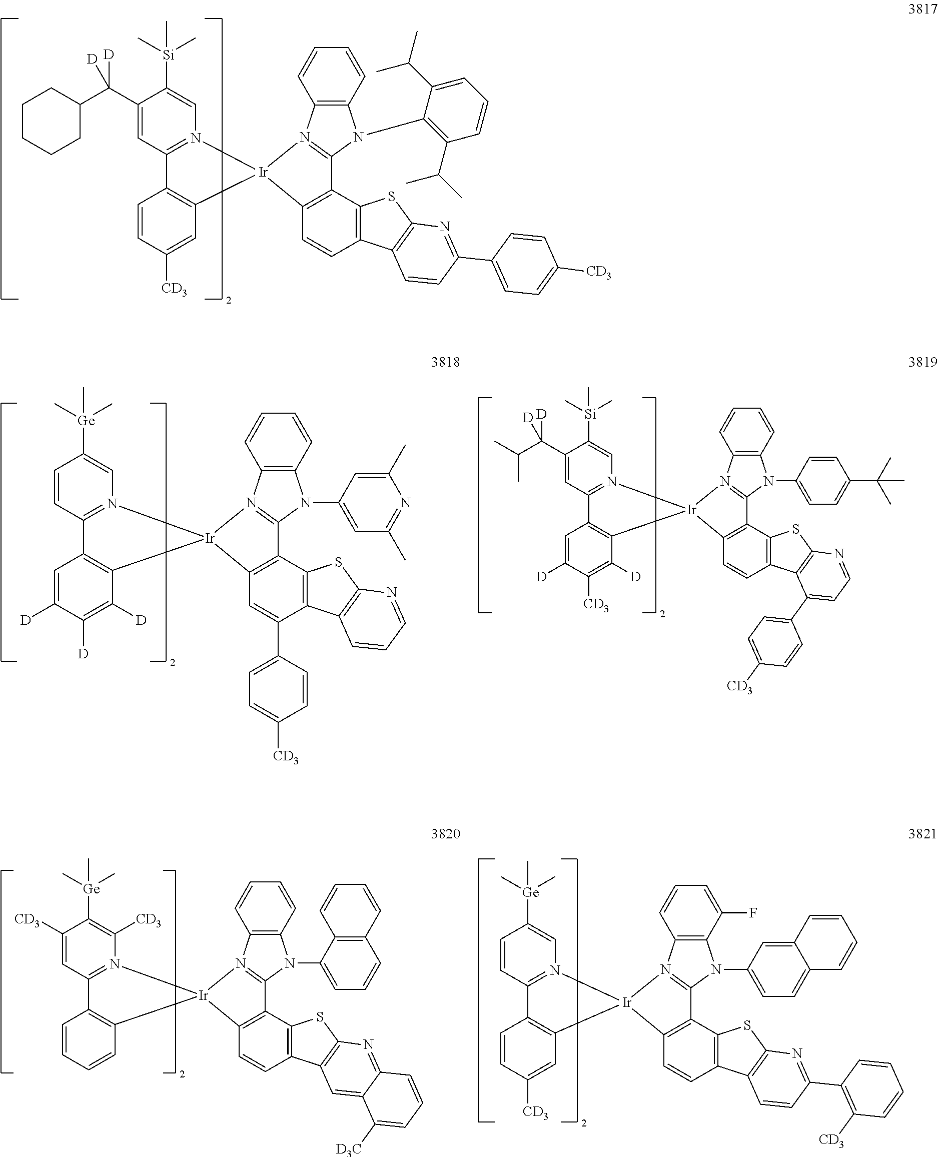

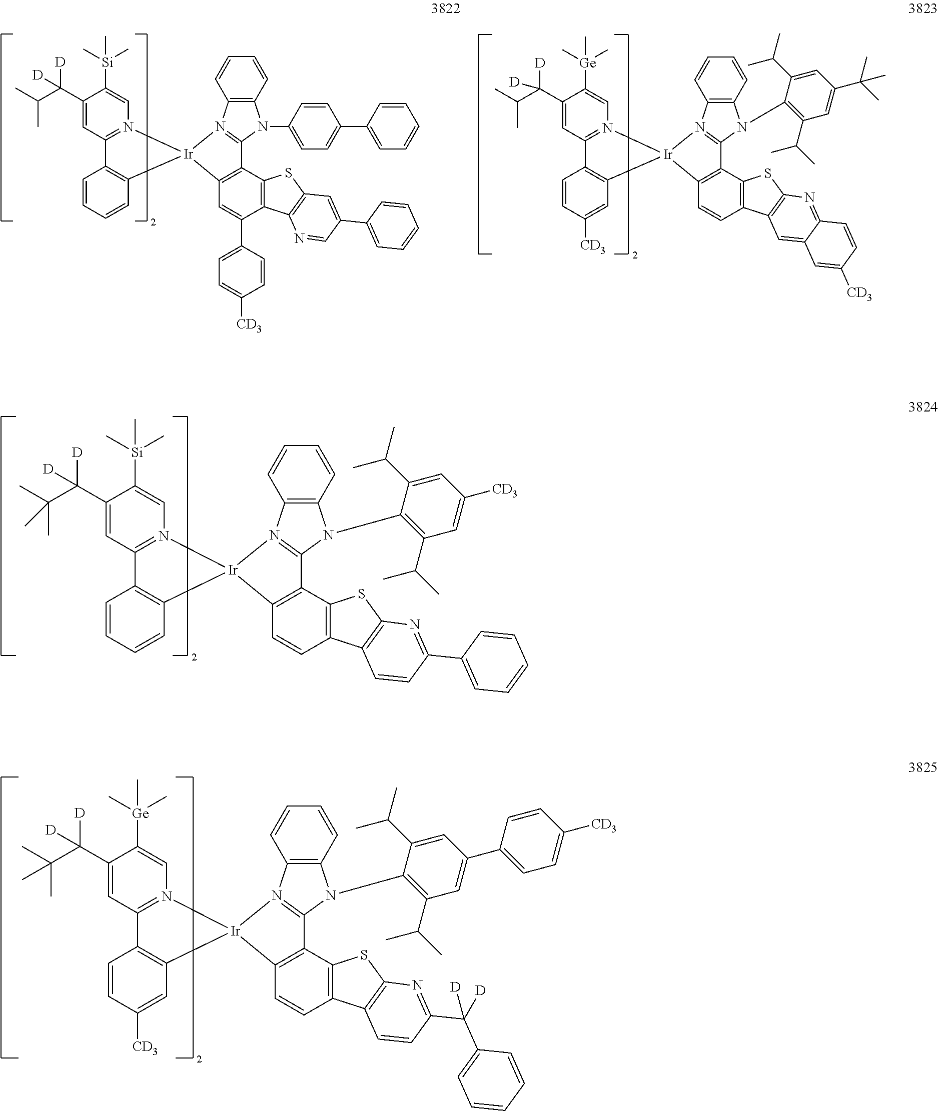

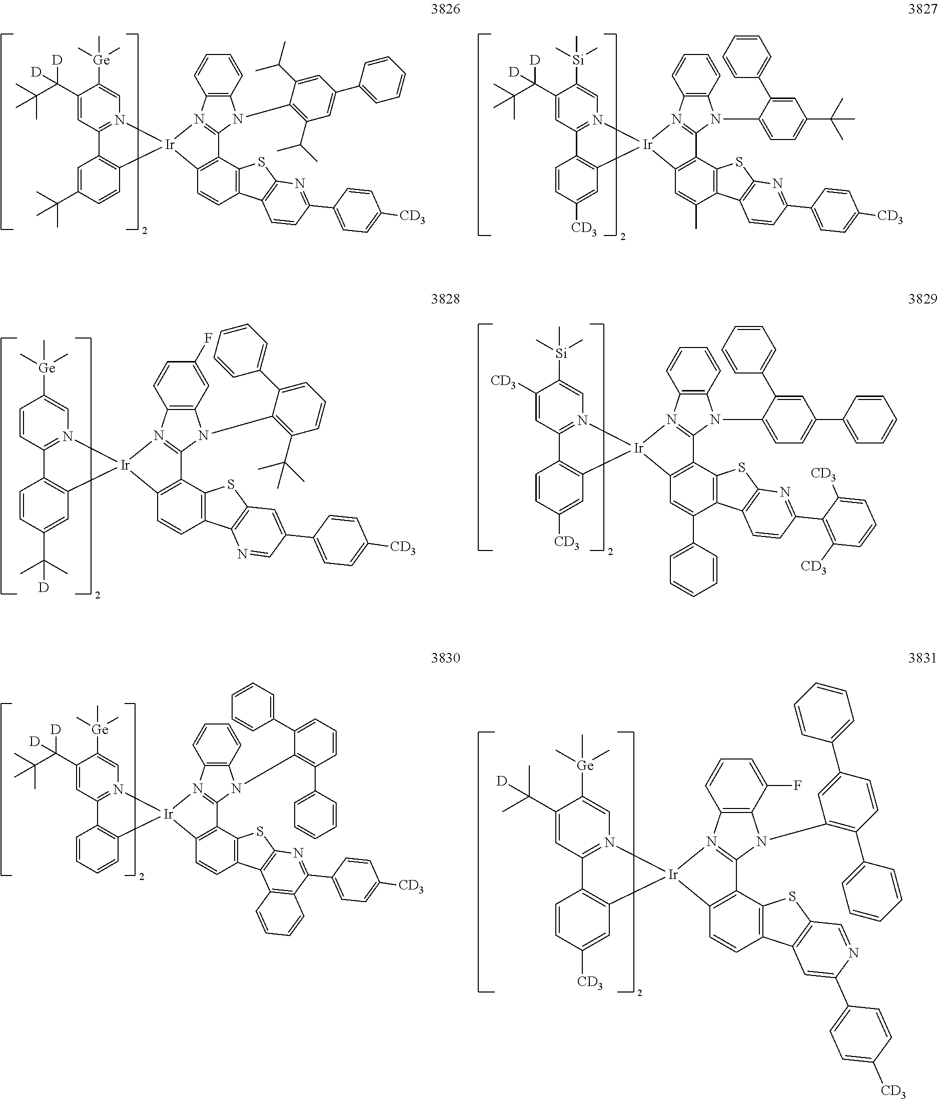

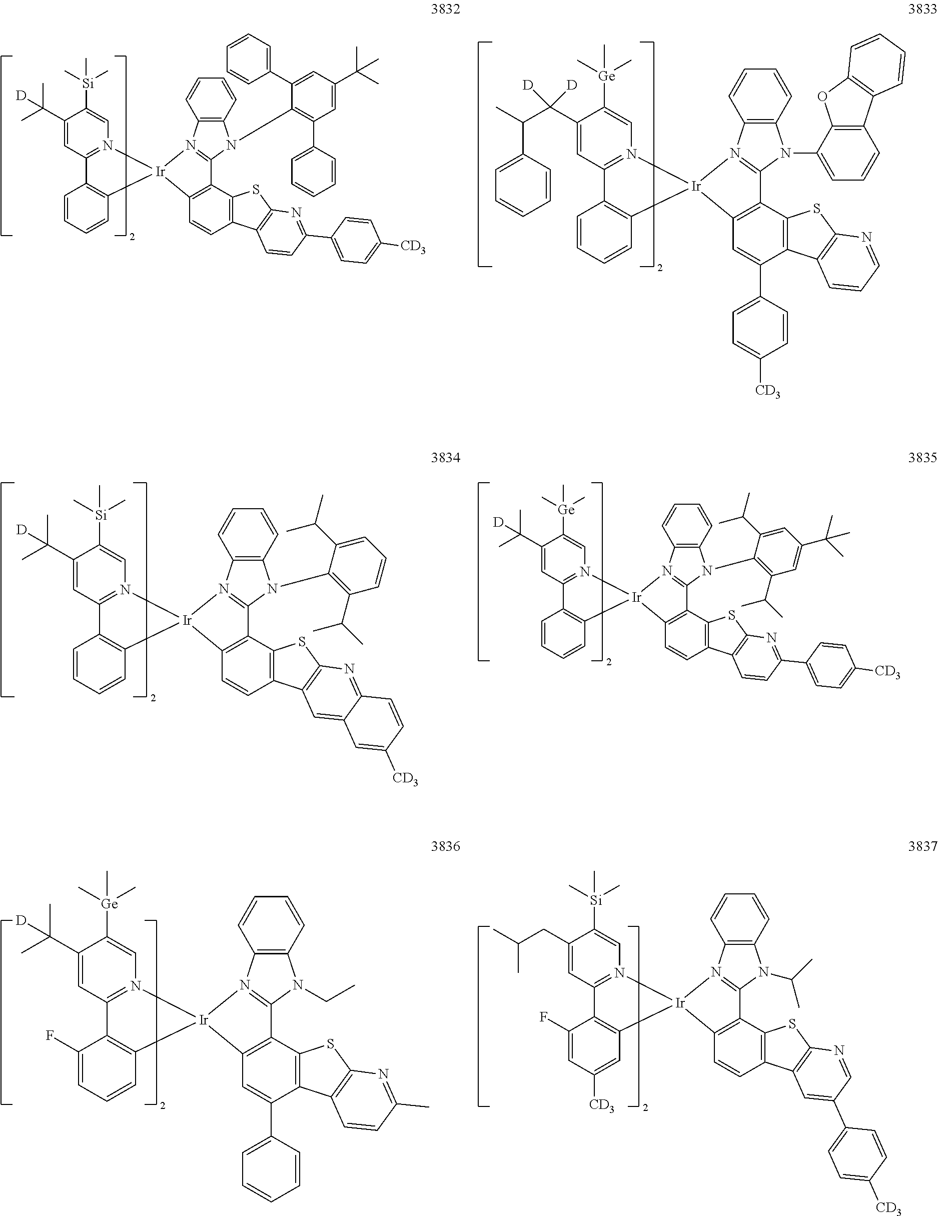

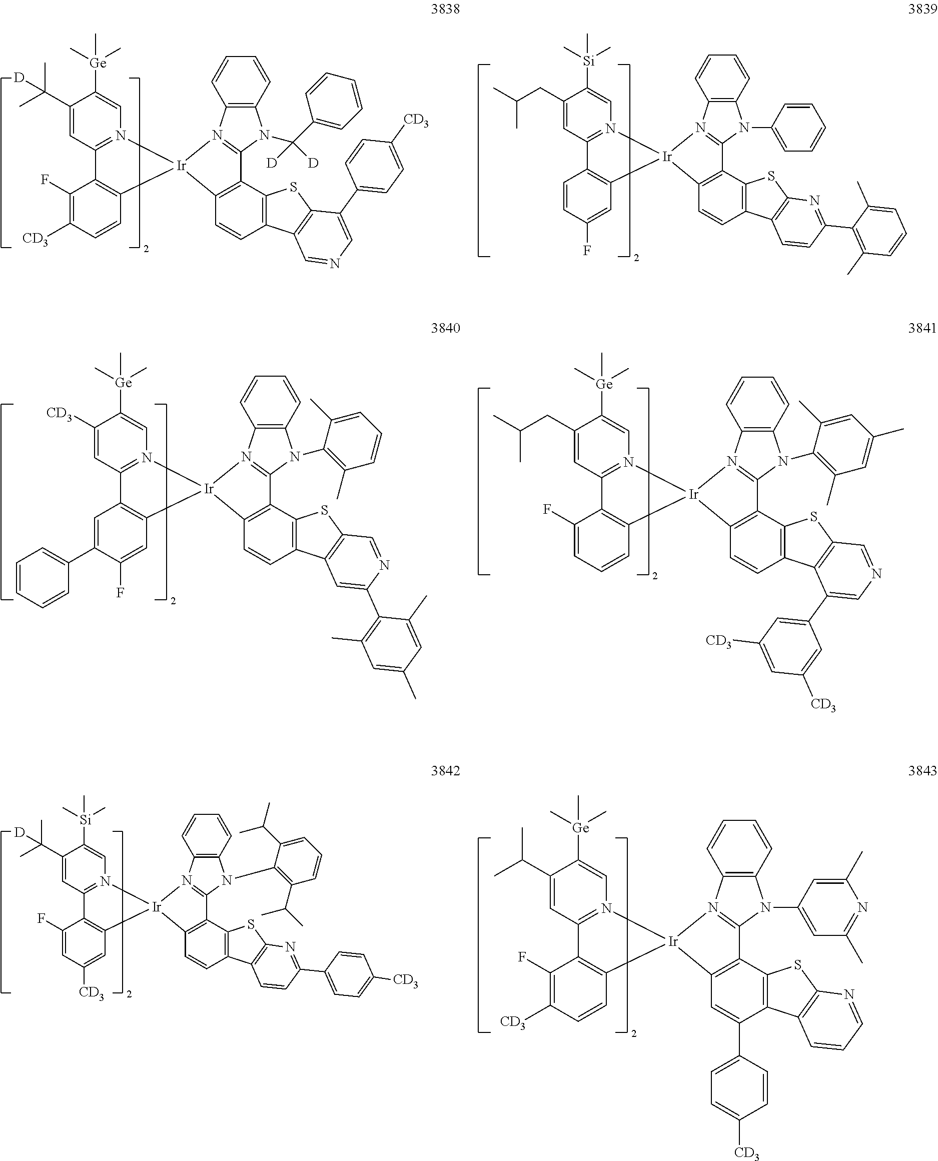

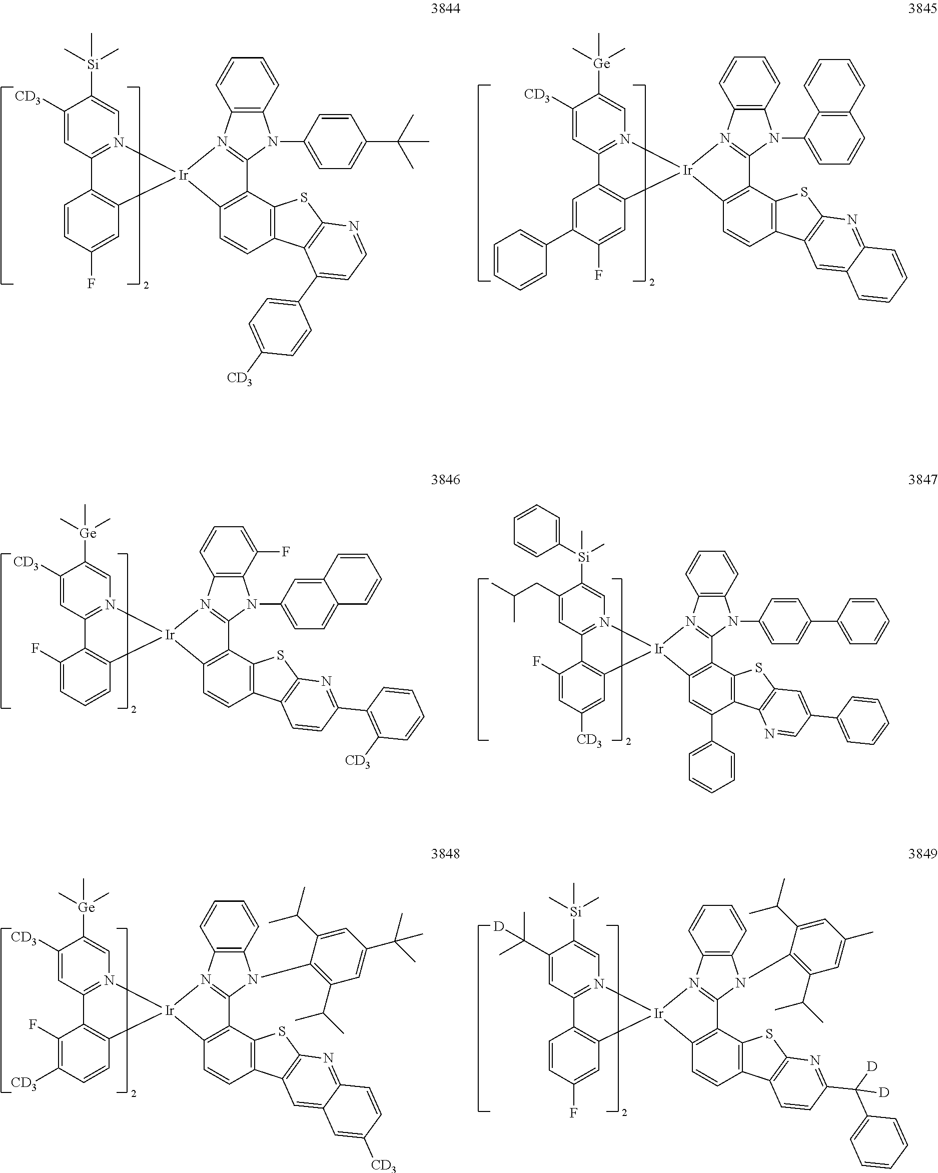

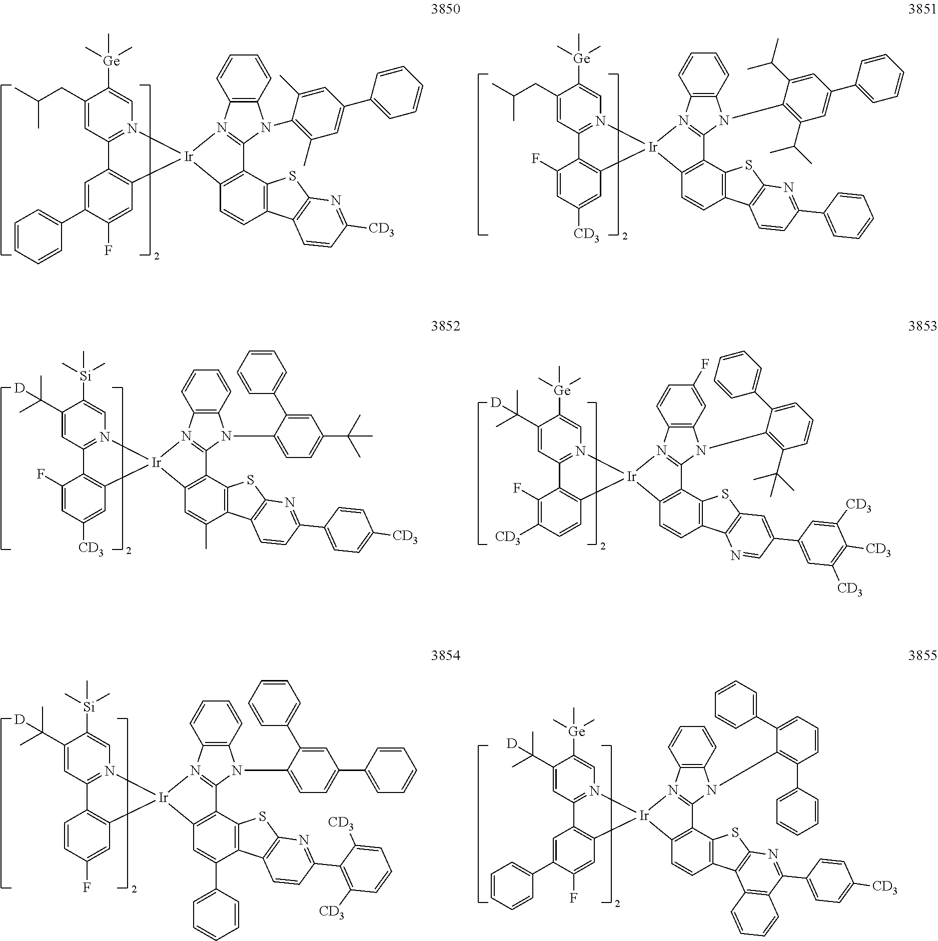

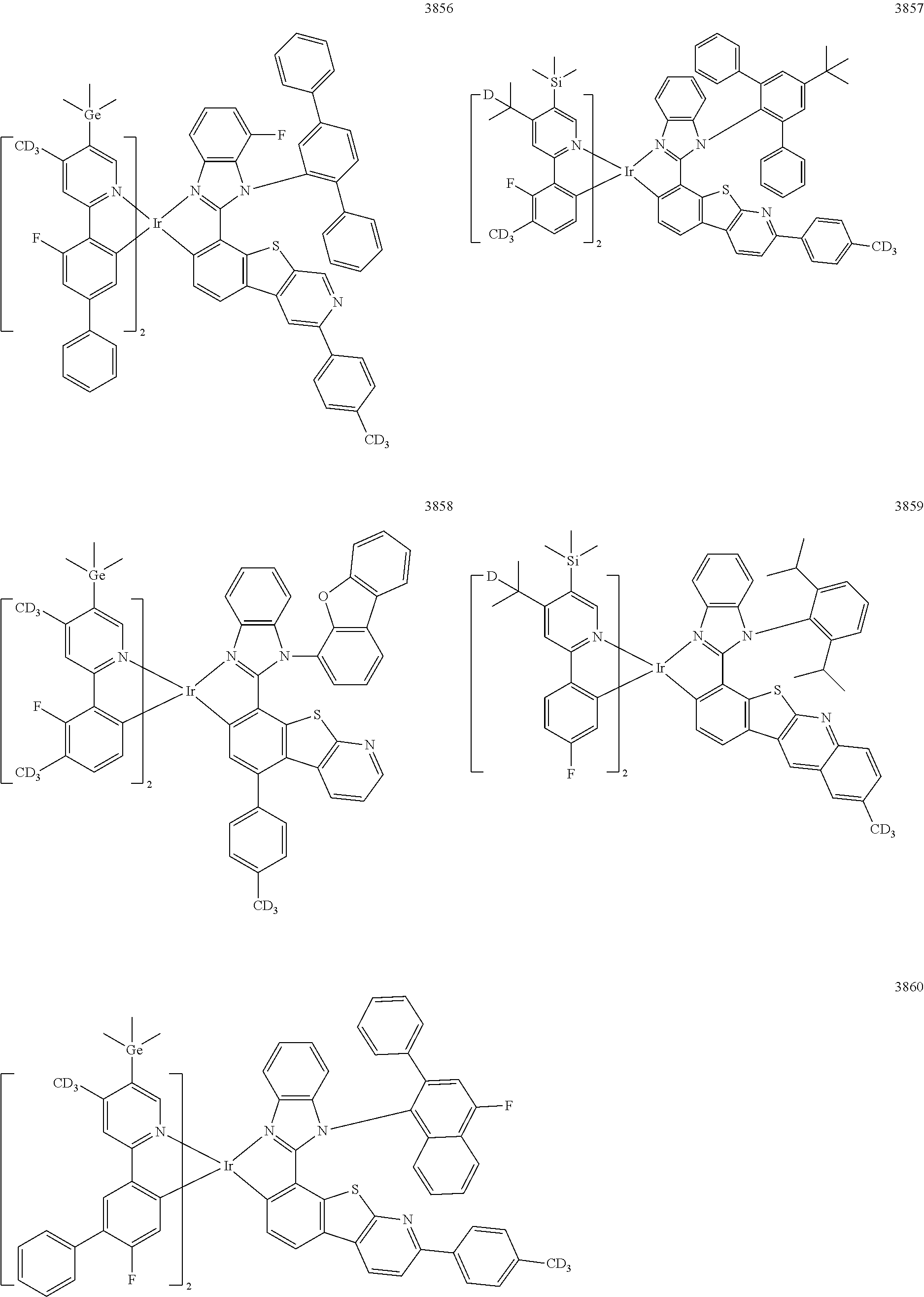

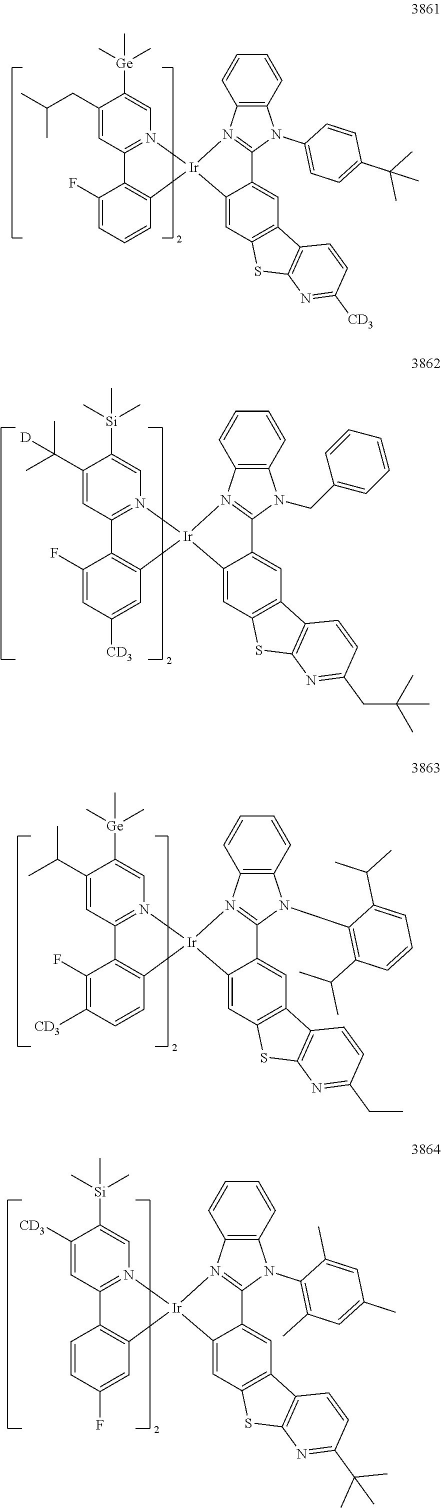

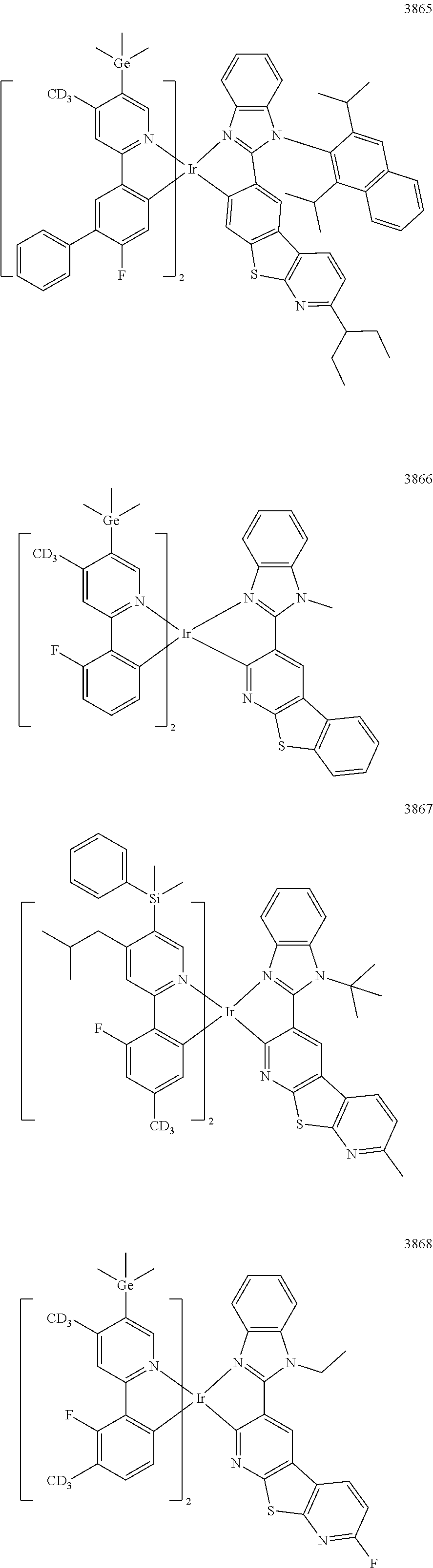

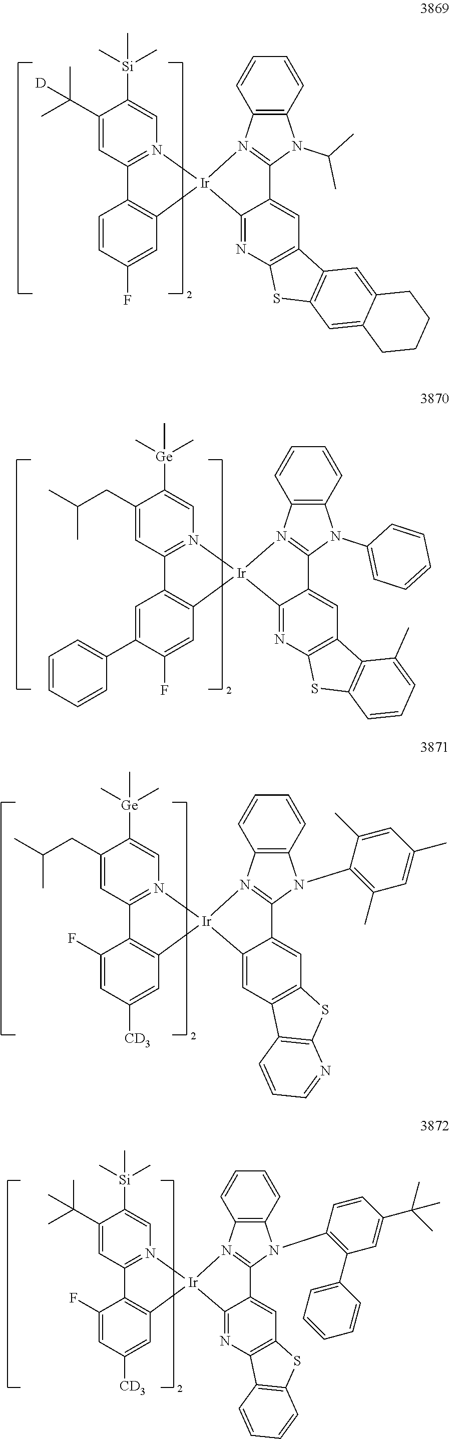

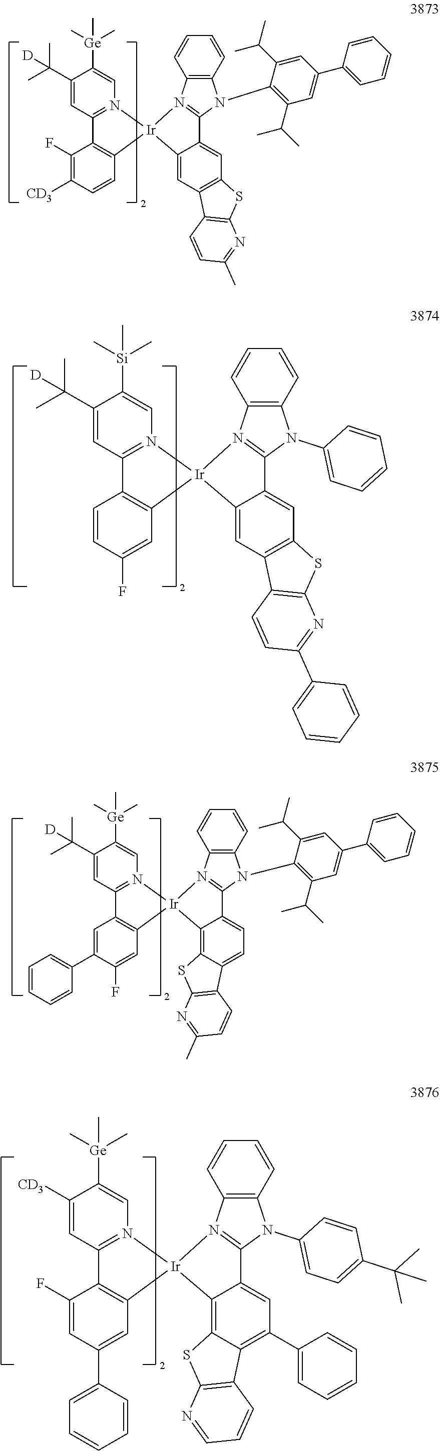

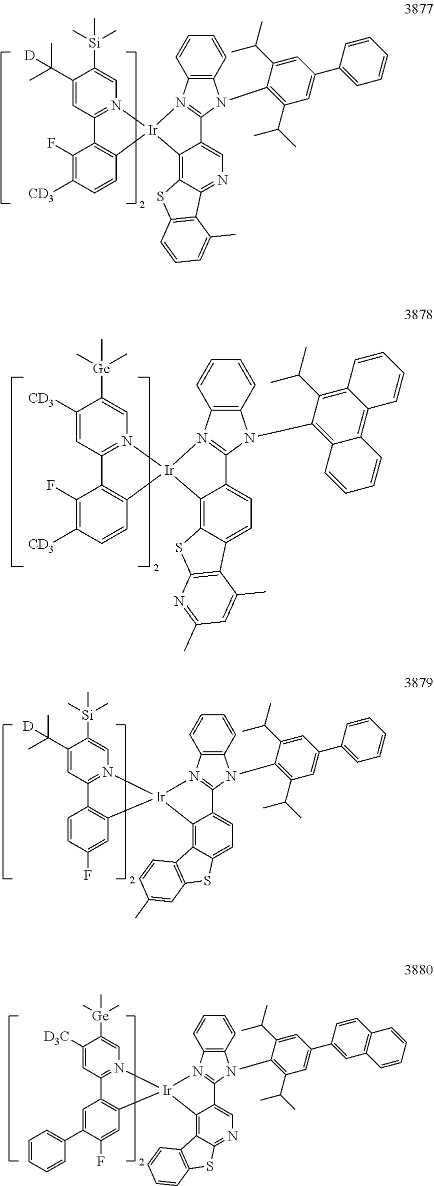

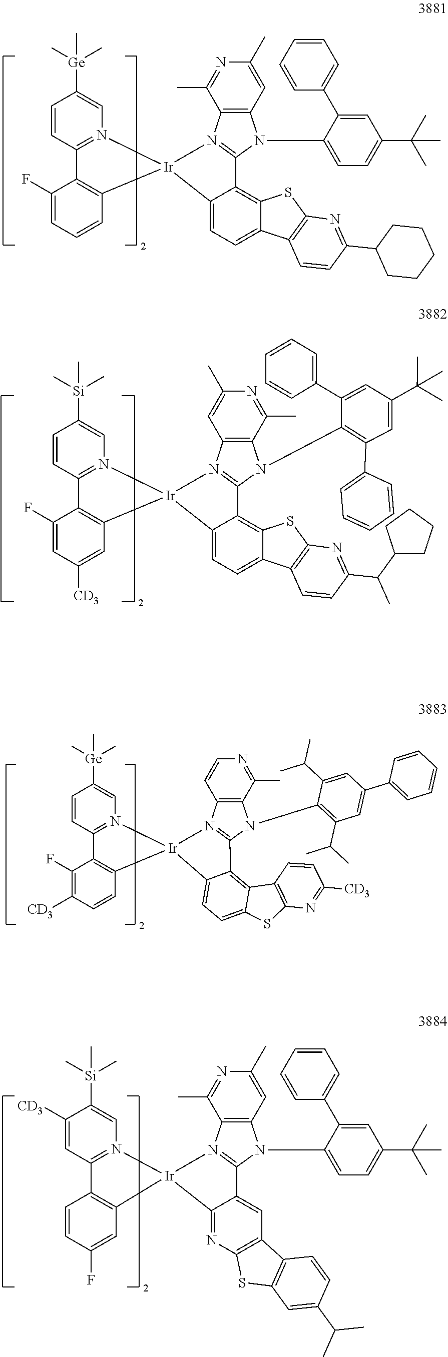

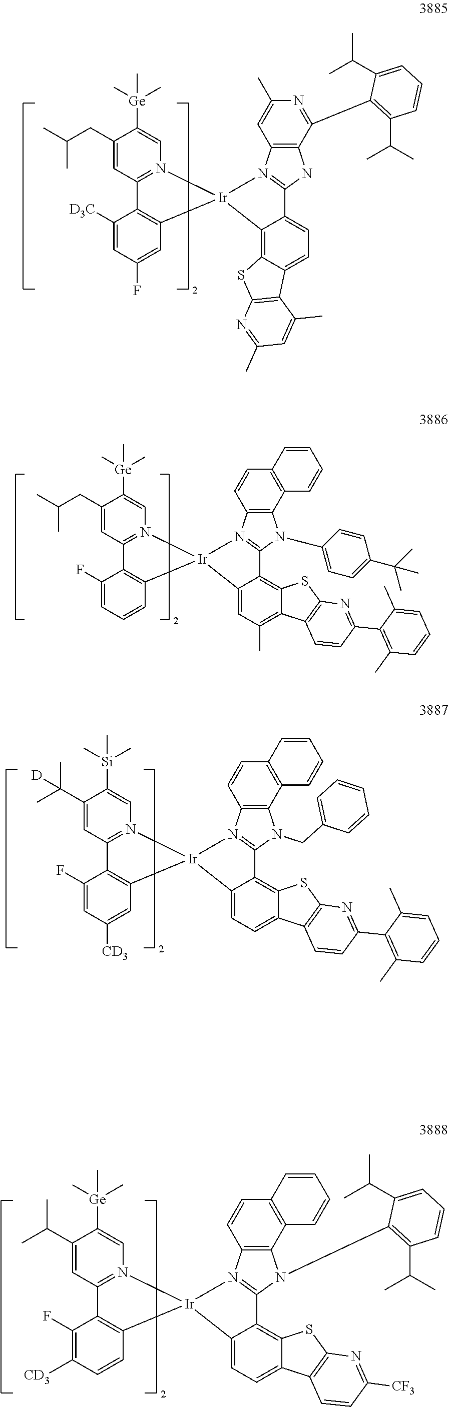

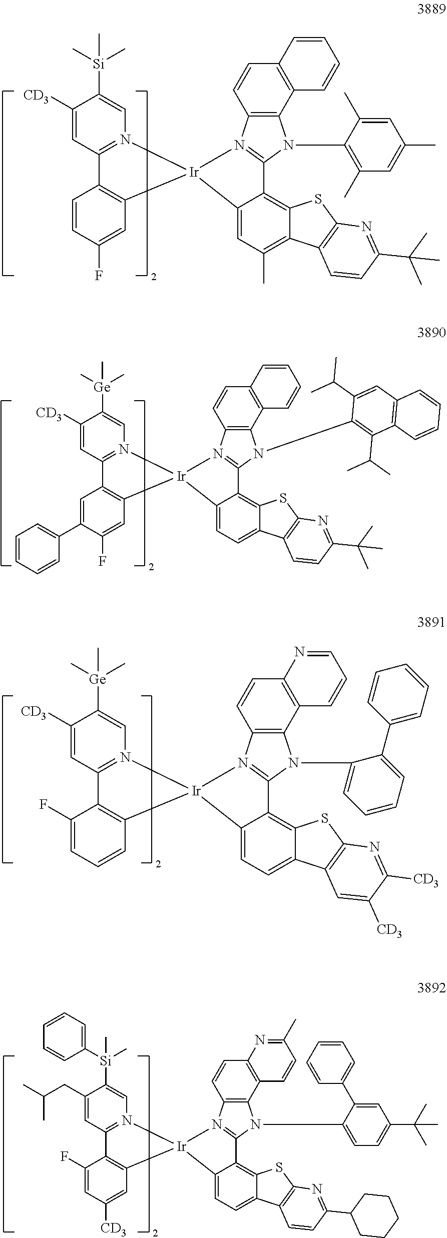

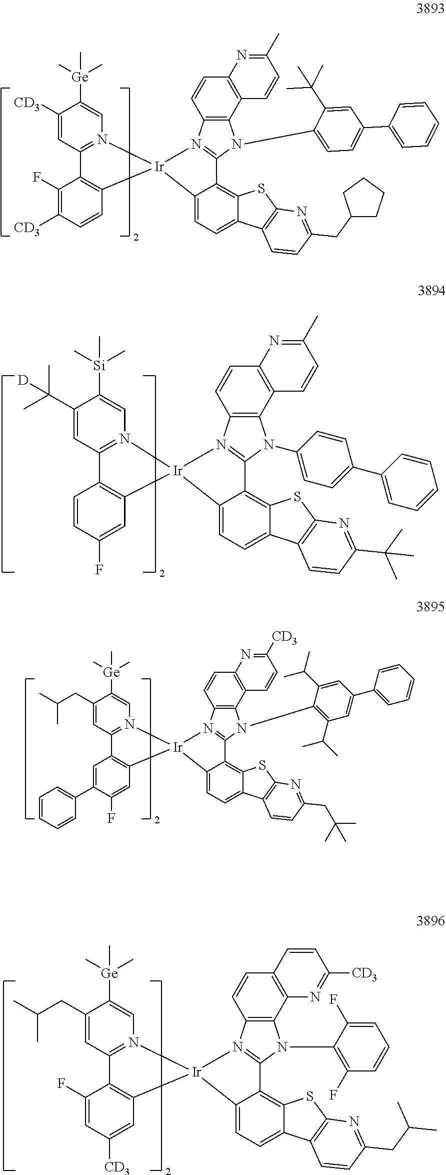

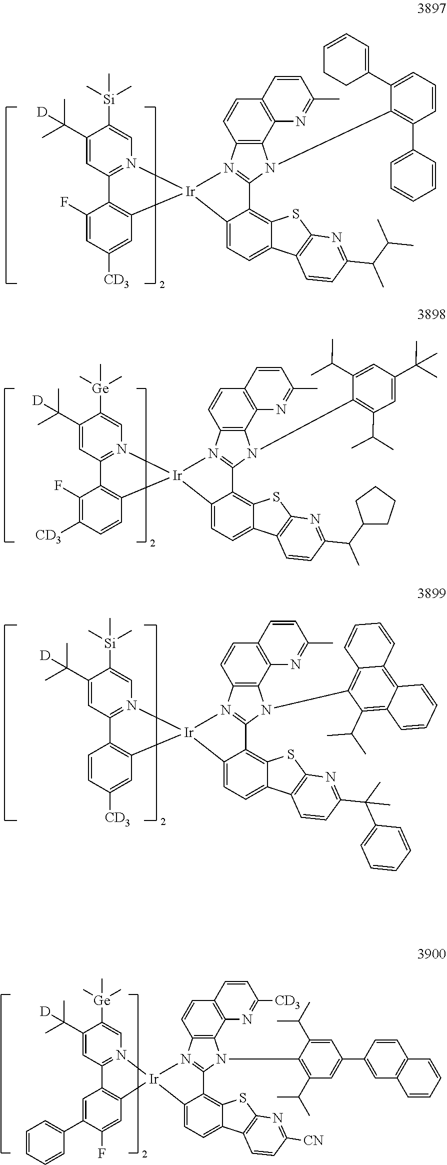

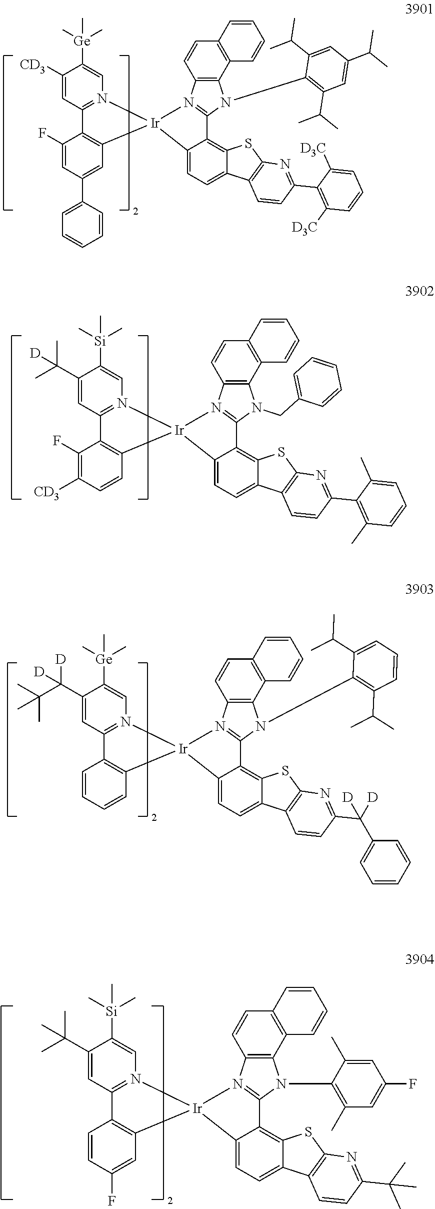

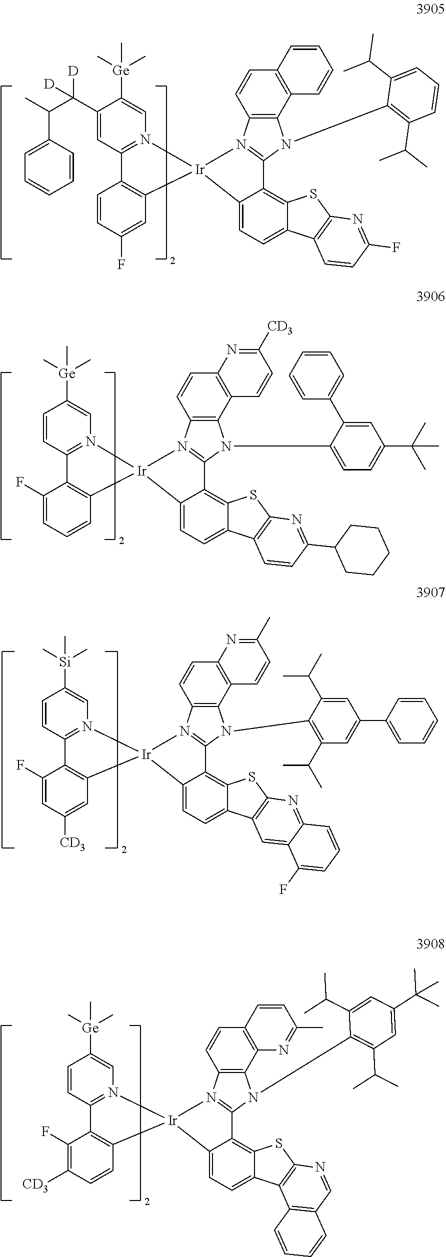

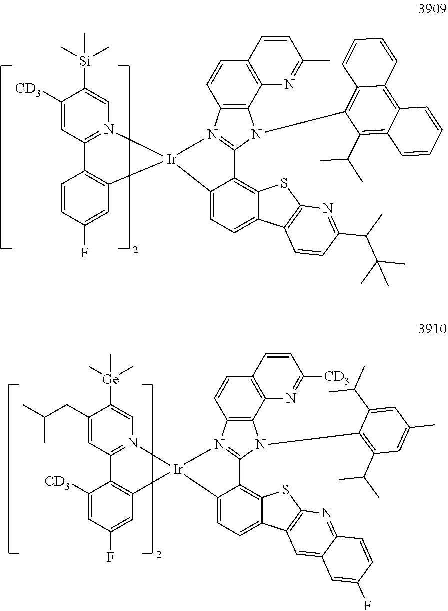

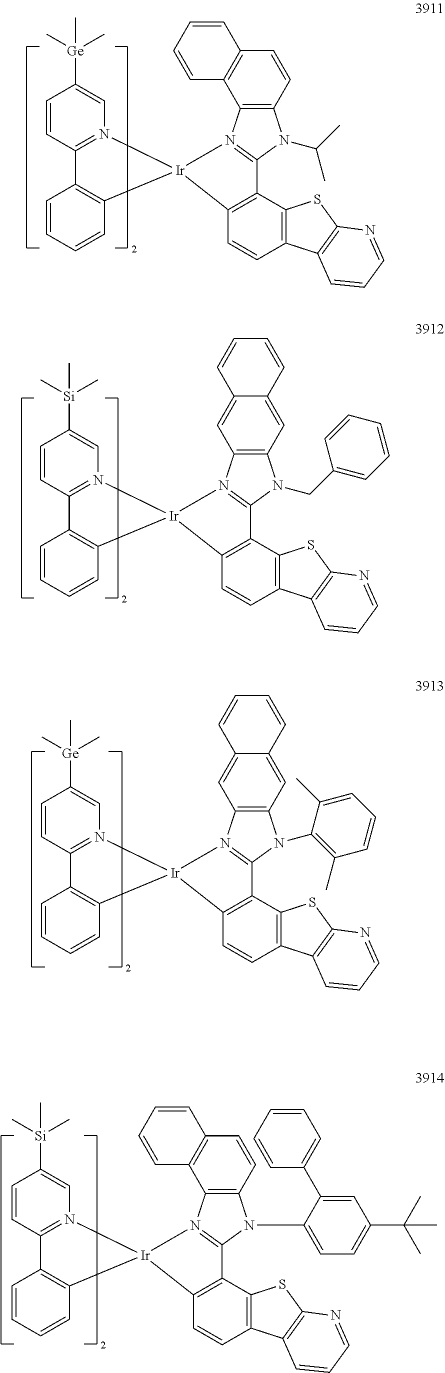

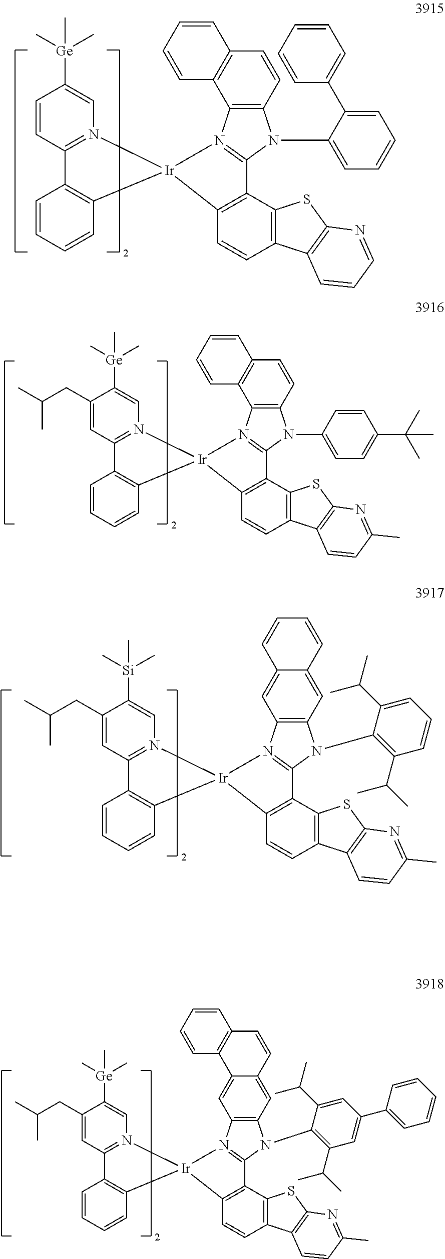

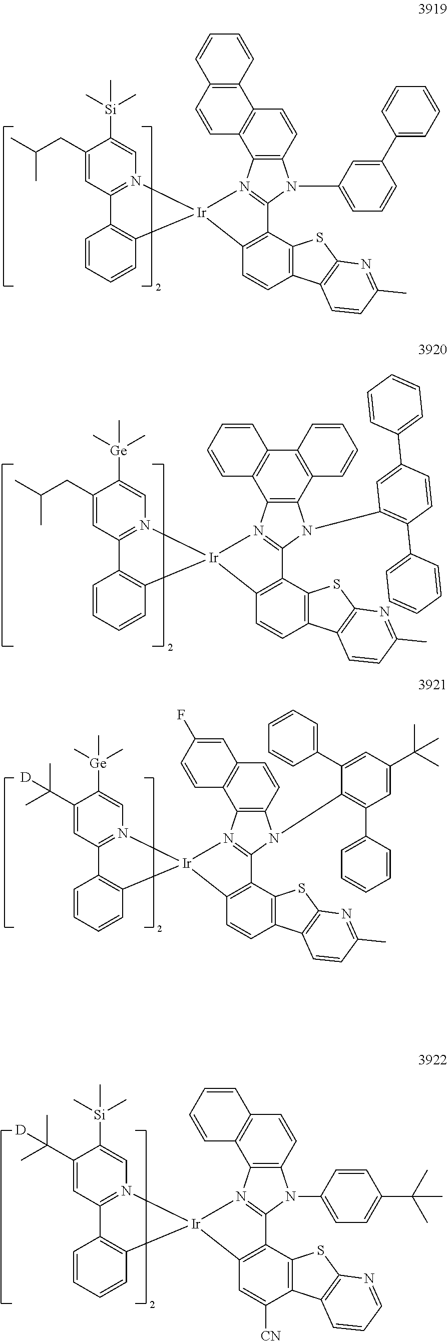

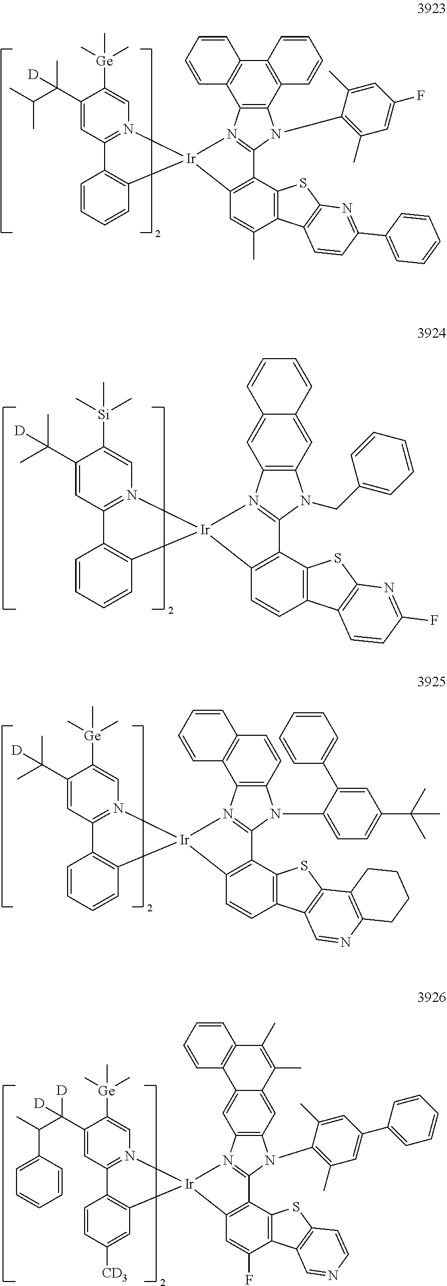

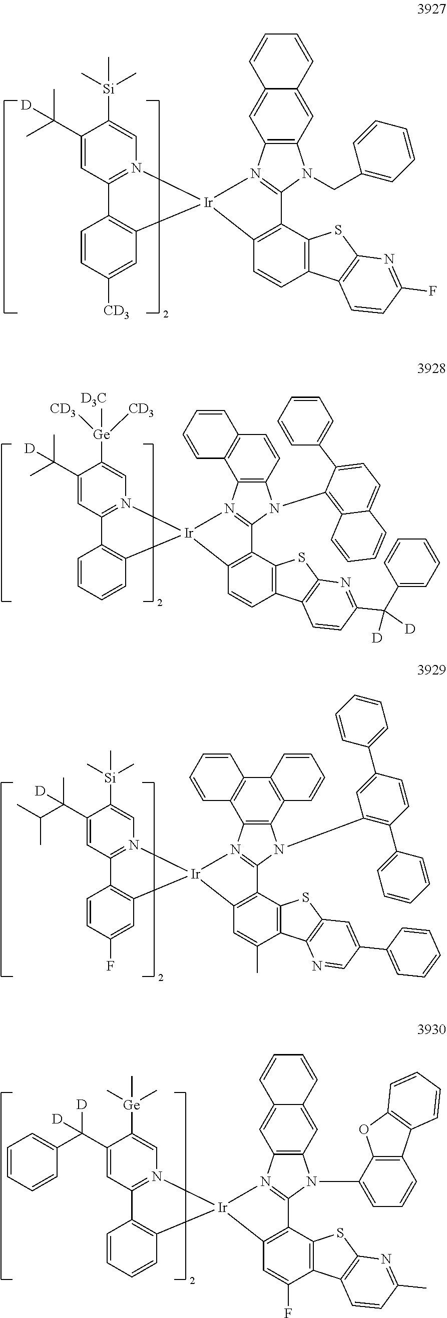

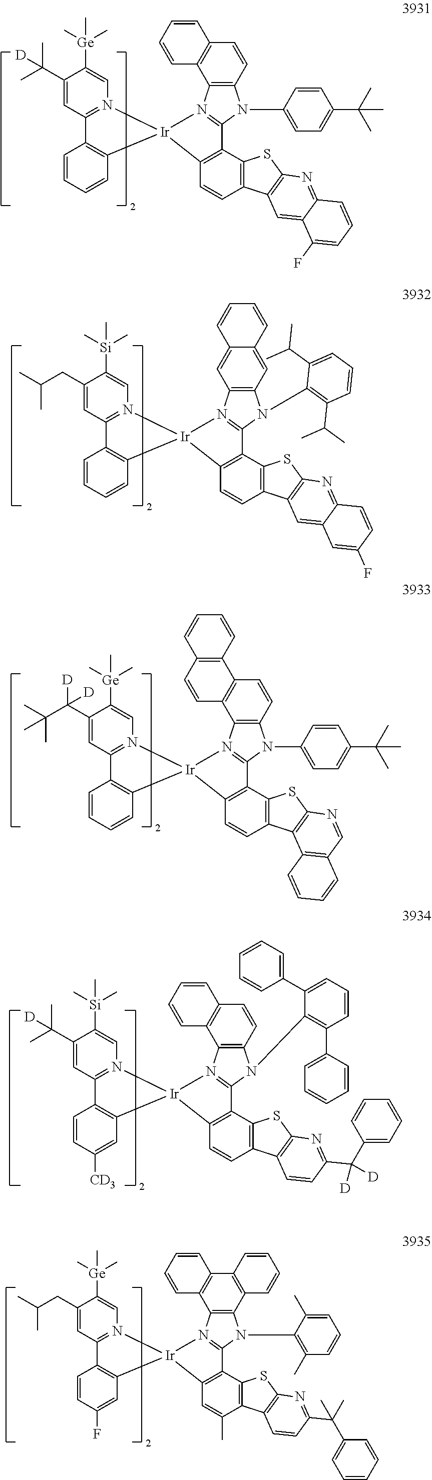

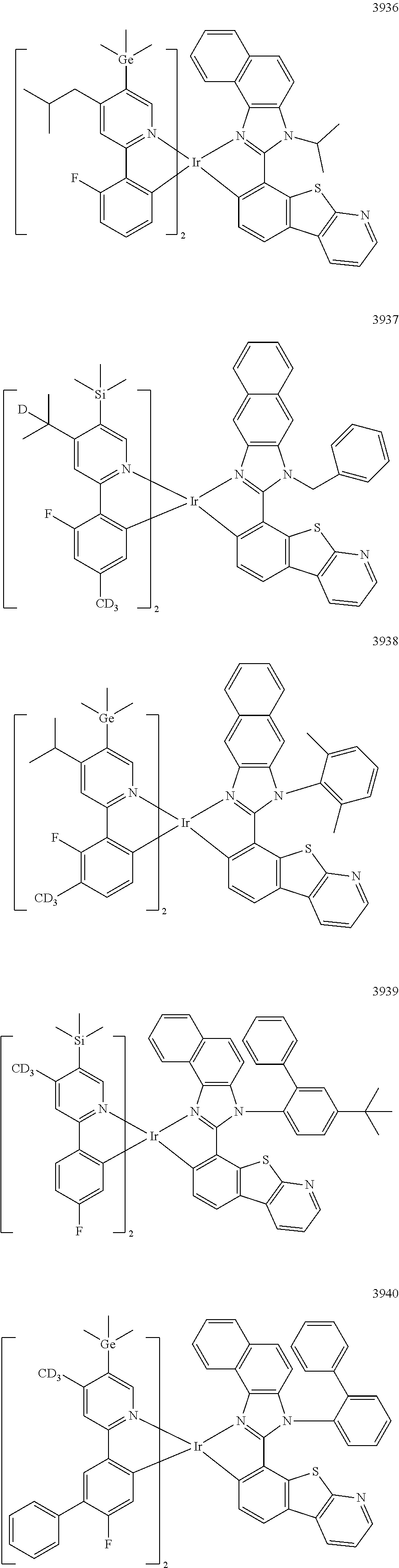

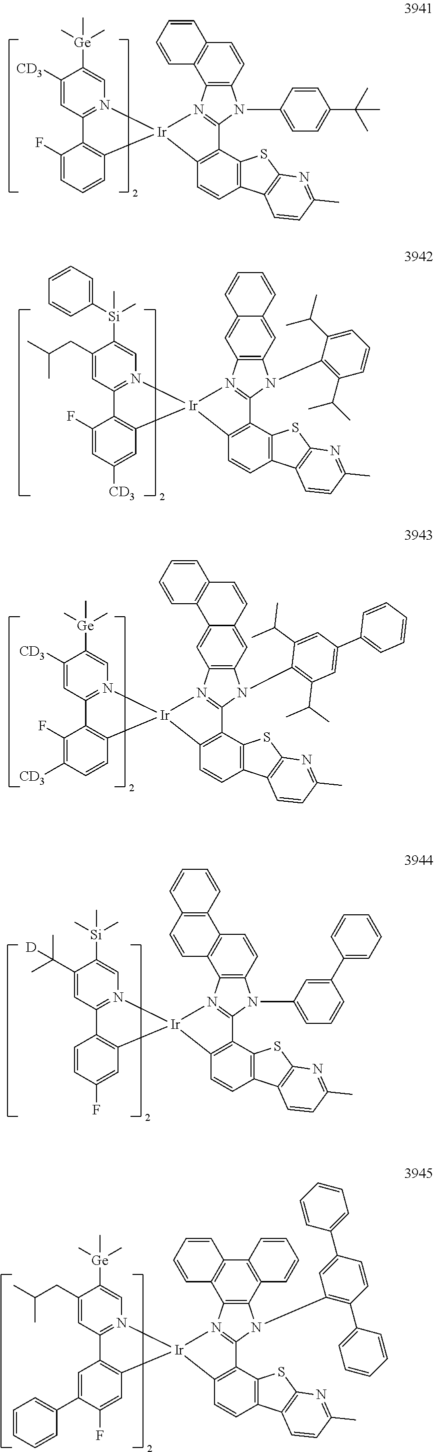

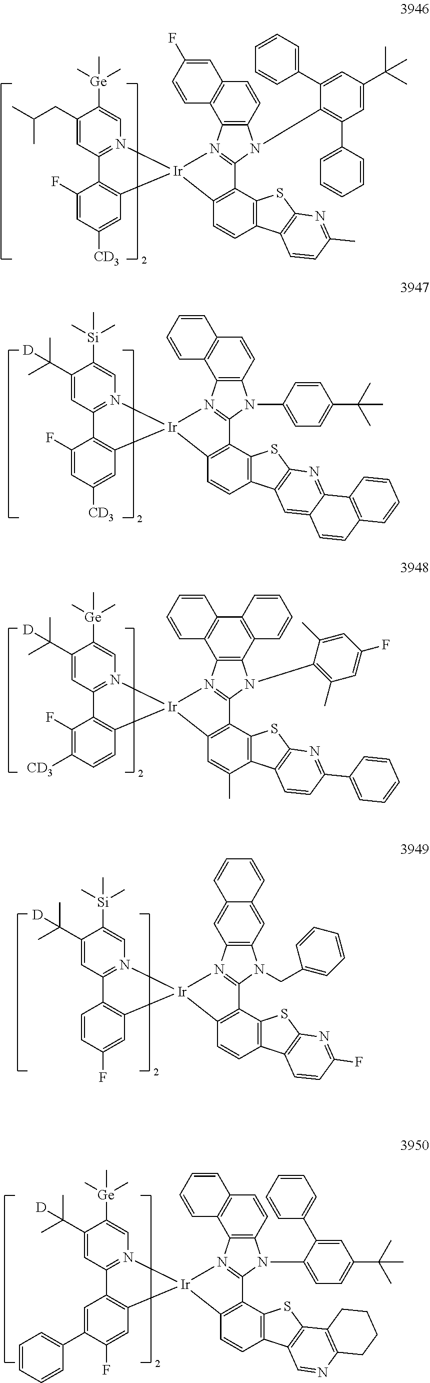

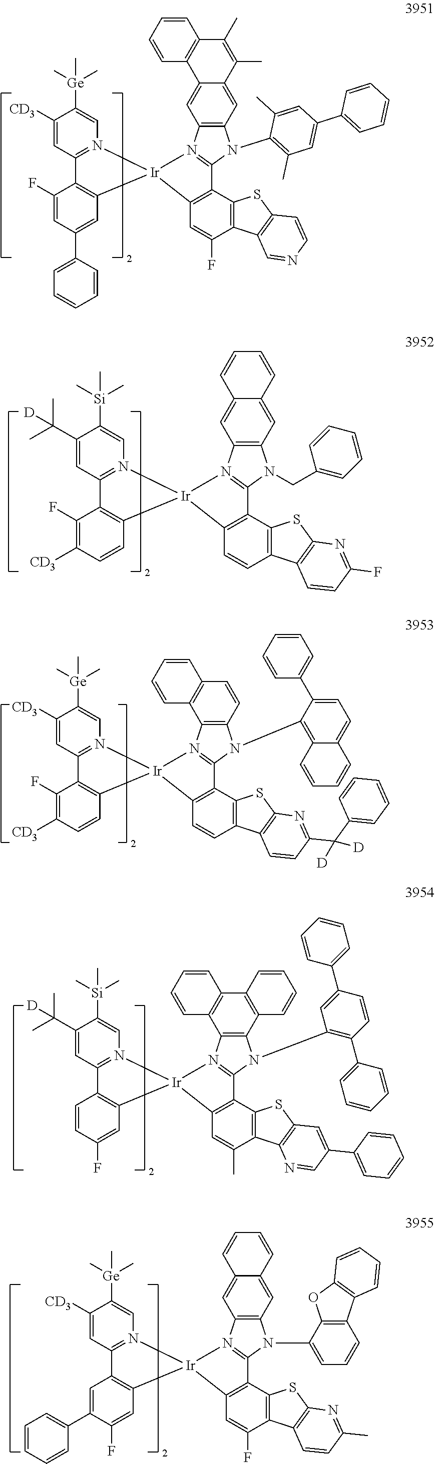

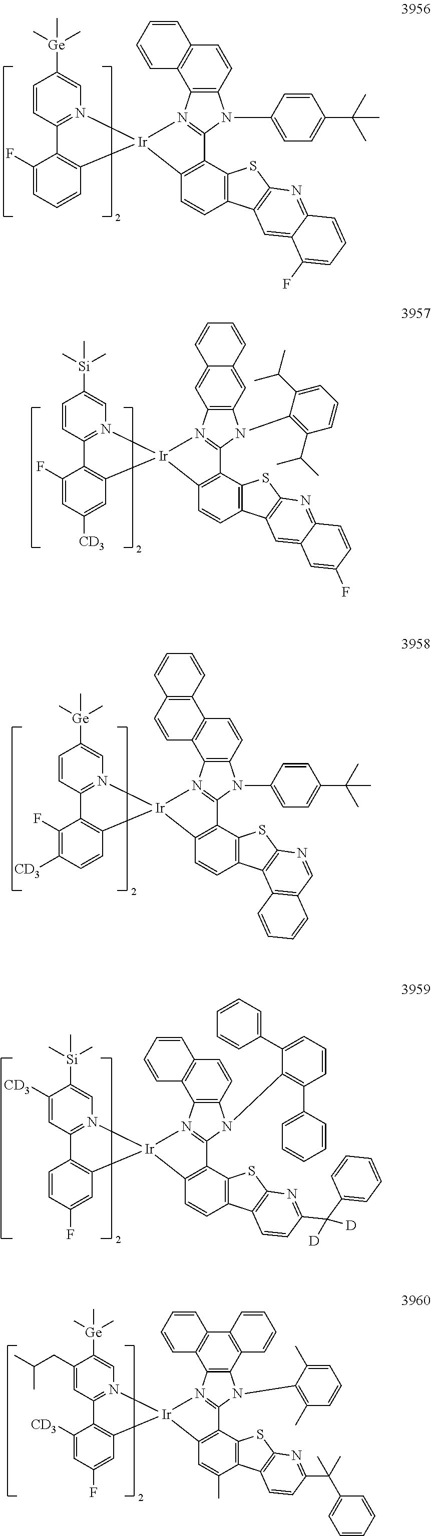

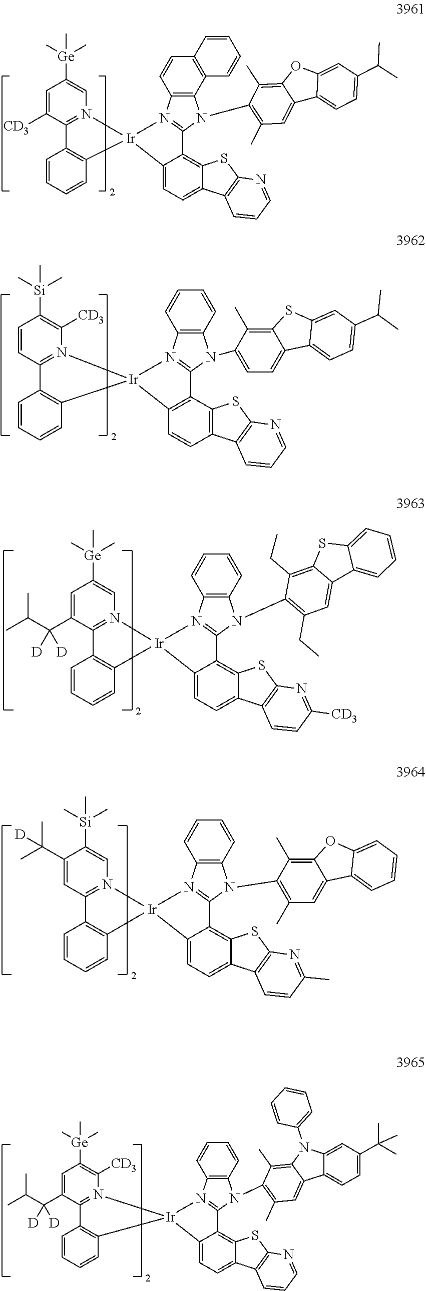

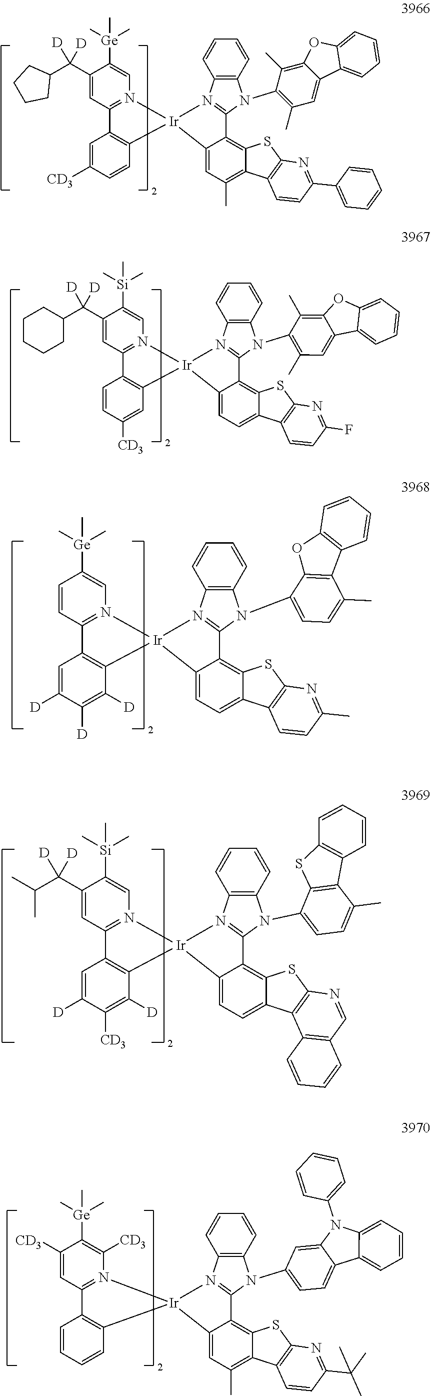

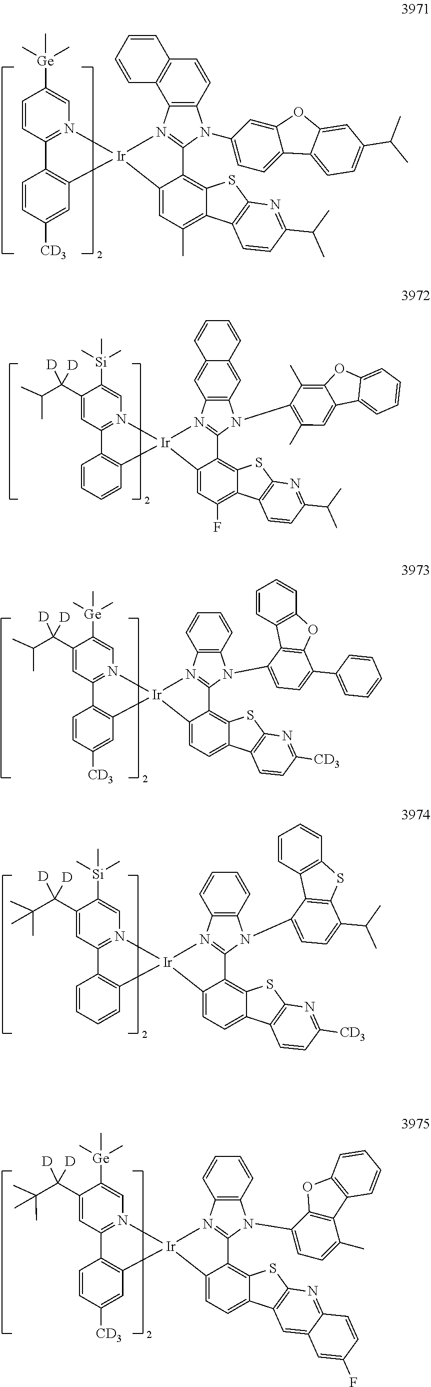

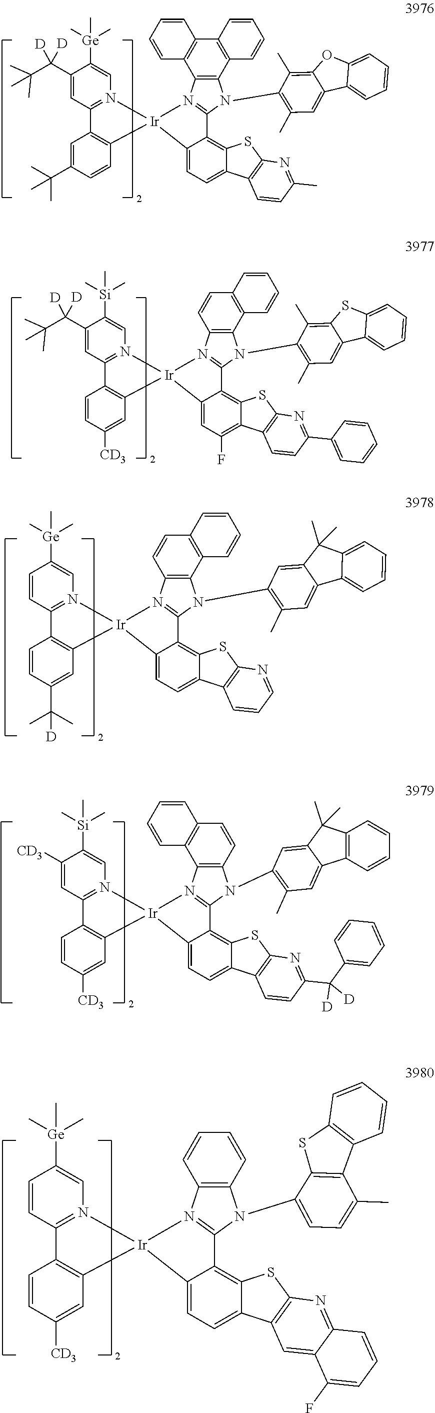

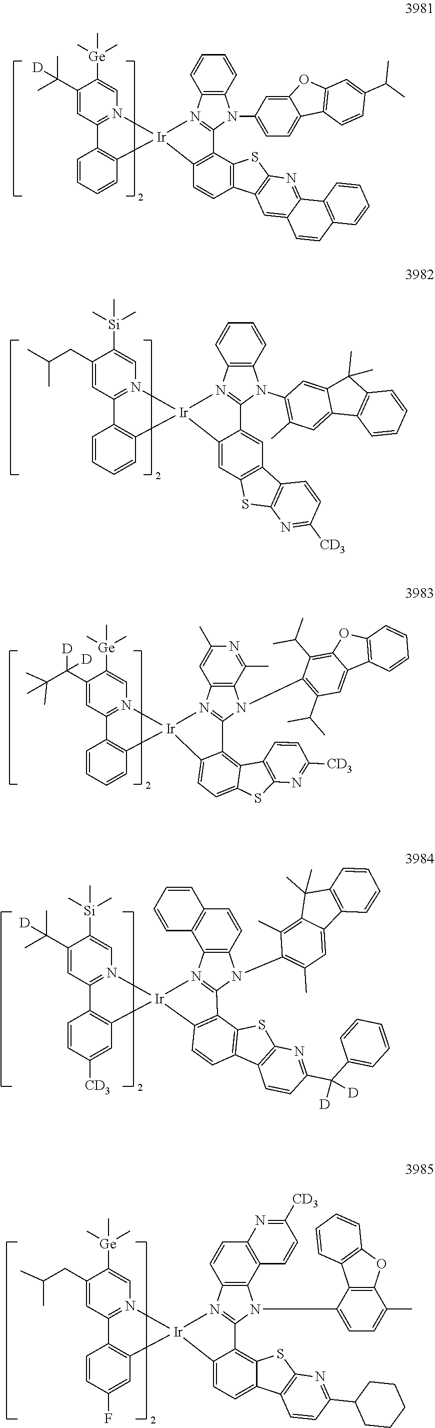

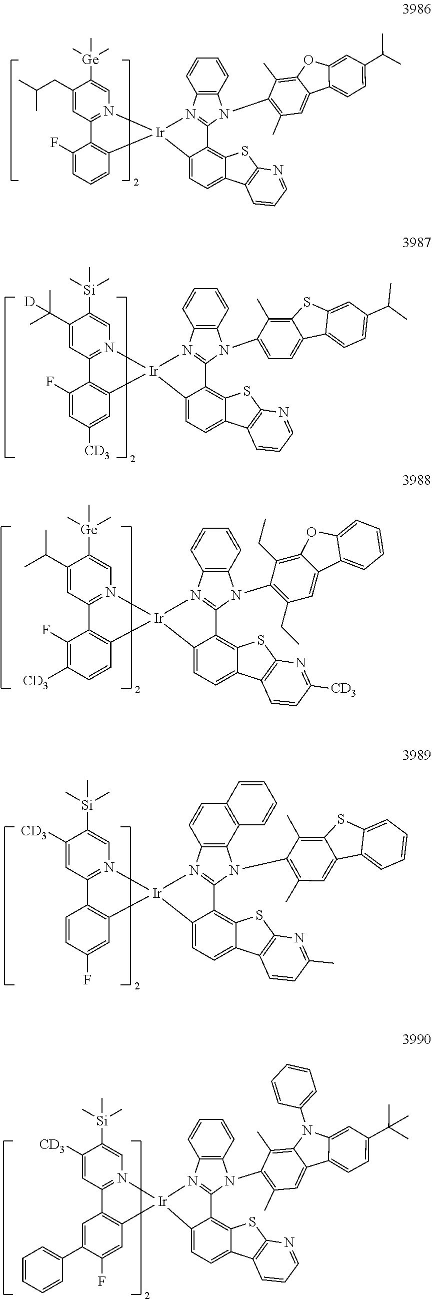

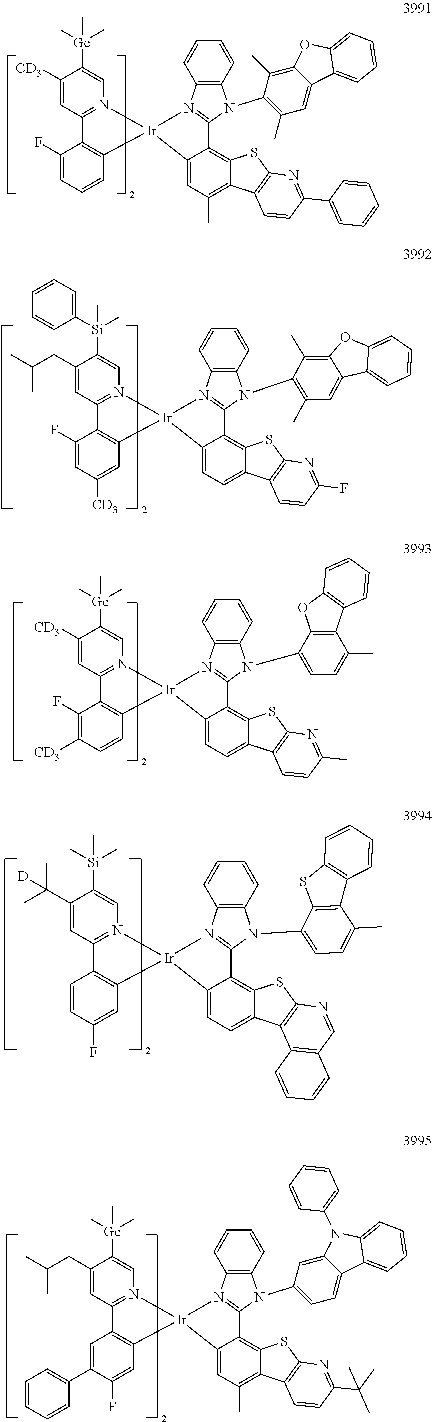

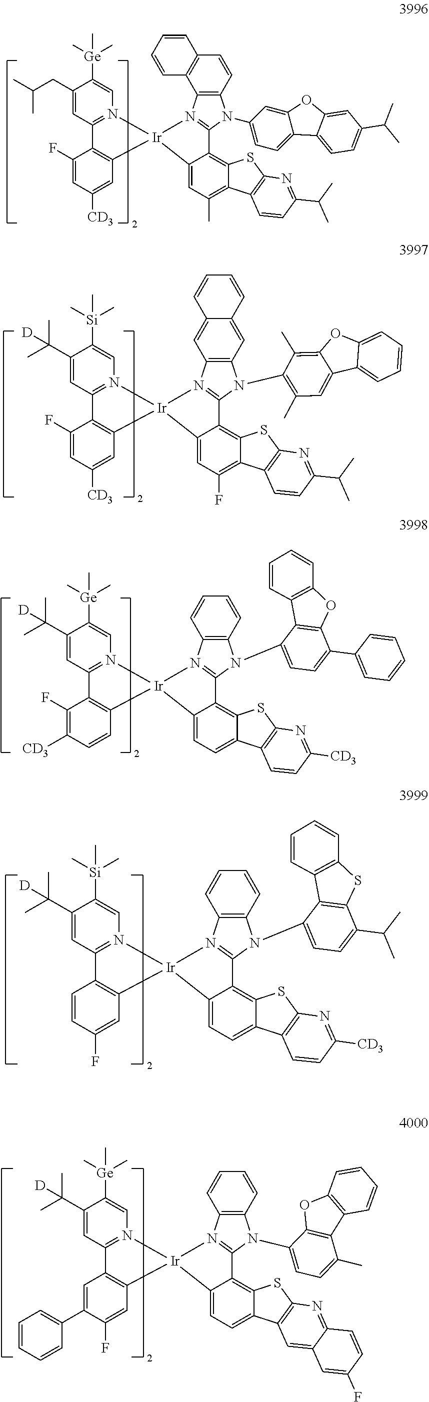

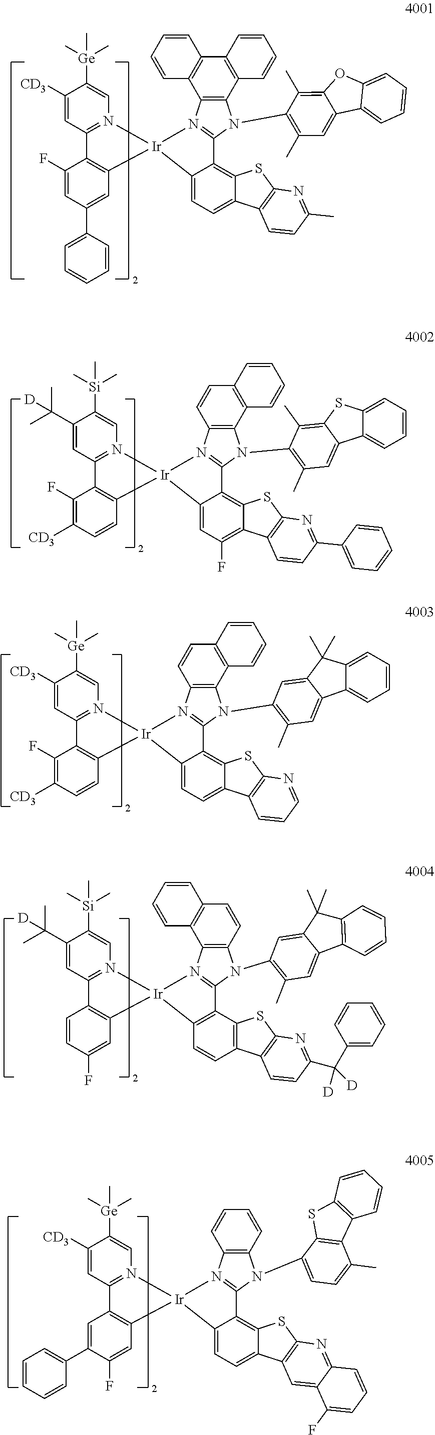

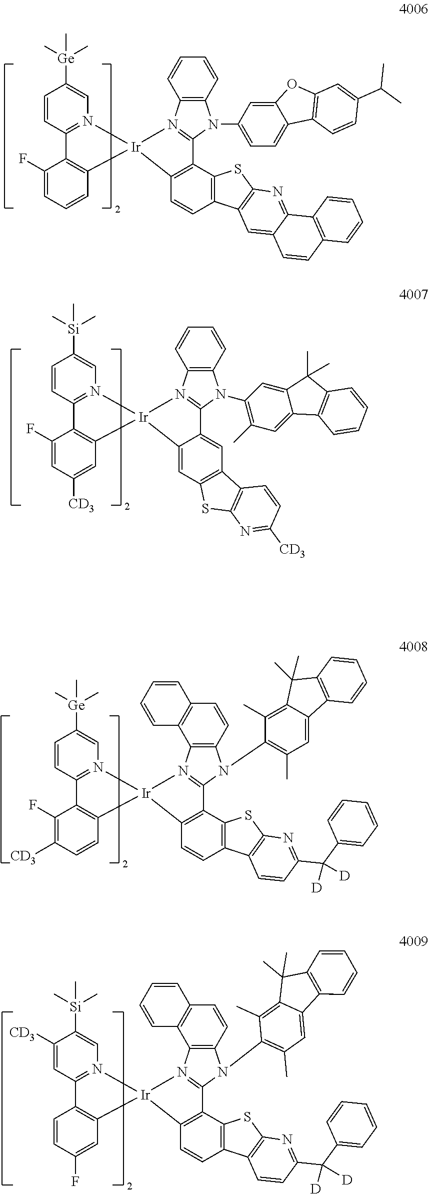

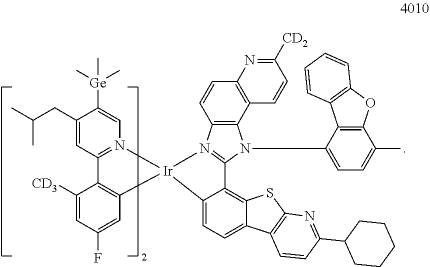

16. An organic light-emitting device comprising:
a first electrode;
a second electrode; and
an organic layer disposed between the first electrode and the second electrode and comprising an emission layer,
wherein the organic layer comprises at least one organometallic compound of claim 1.

17. The organic light-emitting device of claim 16, wherein
the first electrode is an anode,
the second electrode is a cathode,
the organic layer further comprises a hole transport region between the first electrode and the emission layer and an electron transport region disposed between the emission layer and the second electrode,
the hole transport region comprises a hole injection layer, a hole transport layer, an electron blocking layer, a buffer layer, or a combination thereof, and
the electron transport region comprises a hole blocking layer, an electron transport layer, an electron injection layer, or a combination thereof.

18. The organic light-emitting device of claim 16, wherein
the emission layer comprises the at least one organometallic compound.

19. The organic light-emitting device of claim 18, wherein
the emission layer emits green light.

20. An electronic apparatus comprising the organic light-emitting device of claim 16.
